(19) United States
(12) Patent Application Publication
(10) Pub. No.: US 2023/0025356 A1
(43) Pub. Date: Jan. 26, 2023

(54) COMPOSITION, LAYER INCLUDING THE COMPOSITION, LIGHT-EMITTING DEVICE INCLUDING THE COMPOSITION, AND ELECTRONIC APPARATUS INCLUDING THE LIGHT-EMITTING DEVICE

(71) Applicant: Samsung Electronics Co., Ltd., Suwon-si (KR)

(72) Inventors: Sunghun Lee, Hwaseong-si (KR); Seungyeon Kwak, Suwon-si (KR); Sungmin Kim, Incheon (KR); Hyungjun Kim, Suwon-si (KR); Myungsun Sim, Suwon-si (KR); Jeoungin Yi, Seoul (KR); Byoungki Choi, Hwaseong-si (KR); Kyuyoung Hwang, Anyang-si (KR)

(21) Appl. No.: 17/830,770

(22) Filed: Jun. 2, 2022

(30) Foreign Application Priority Data
Jun. 3, 2021 (KR) 10-2021-0072366
May 31, 2022 (KR) 10-2022-0066796

(51) Int. Cl. H01L 51/00; C07F 15/00; C09K 11/06

(52) U.S. Cl. CPC H01L 51/0087; C07F 15/0086; C09K 11/06; H01L 51/0085; H01L 51/0094; H01L 51/5012

(57) ABSTRACT

A composition including a first compound and a second compound, wherein the first compound is an organometallic compound including platinum and a tetradentate ligand bound thereto, and the second compound is an organometallic compound including iridium, μ(Pt) is about 0.5 debye to about 5.0 debye, μ(Pt) is less than μ(Ir), μ(Pt) is a dipole moment of the first compound, μ(Ir) is a dipole moment of the second compound, and each of μ(Pt) and μ(Ir) is calculated based on density functional theory as described herein.

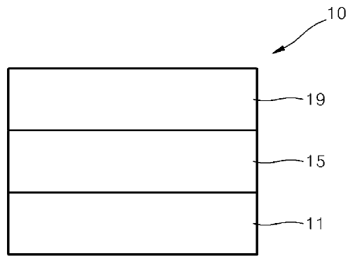

### CROSS-REFERENCE TO RELATED APPLICATION

This application is based on and claims priority to Korean Patent Applications Nos. 10-2021-0072366, filed on Jun. 3, 2021, and 10-2022-0066796, filed on May 31, 2022, in the Korean Intellectual Property Office, and all the benefits accruing therefrom under 35 U.S.C. § 119, the entire contents of which are incorporated by reference herein.

### BACKGROUND

### 1. Field

The present application relates to compositions, layers including the compositions, light-emitting devices including the compositions, and electronic apparatuses including the light-emitting devices.

### 2. Description of the Related Art

From among light-emitting devices, organic light-emitting devices (OLEDs) are self-emissive devices, which have improved characteristics in terms of viewing angles, response time, luminance, driving voltage, and response speed. In addition, OLEDs can produce full-color images.

In an example, an organic light-emitting device includes an anode, a cathode, and an organic layer that is arranged between the anode and the cathode, and where the organic layer includes an emission layer. A hole transport region may be arranged between the anode and the emission layer, and an electron transport region may be arranged between the emission layer and the cathode. Holes provided from the anode may move toward the emission layer through the hole transport region, and electrons provided from the cathode may move toward the emission layer through the electron transport region. The holes and the electrons may recombine in the emission layer to produce excitons. These excitons may then transition from an excited state to a ground state to generate light.

### SUMMARY

Provided are compositions that provide excellent luminescence efficiency or the like, layers including the compositions, light-emitting devices including the compositions, and electronic apparatuses including the light-emitting devices.

Additional aspects will be set forth in part in the detailed description, which follows and, in part, will be apparent from the detailed description, or may be learned by practice of the presented exemplary embodiments.

According to an aspect, a composition includes:

a first compound; and

a second compound,

wherein:

the first compound is an organometallic compound including platinum (Pt) and a tetradentate ligand bound thereto,

the second compound is an organometallic compound including iridium (Ir),

μ(Pt) is about 0.5 debye to about 5.0 debye,

μ(Pt) is less than μ(Ir),

μ(Pt) indicates a dipole moment of the first compound,

μ(Ir) indicates a dipole moment of the second compound, and

each of μ(Pt) and μ(Ir) is calculated based on density functional theory (DFT).

According to another aspect, a layer includes the composition.

According to still another aspect, a light-emitting device includes a first electrode; a second electrode; and an organic layer arranged between the first electrode and the second electrode, wherein the organic layer includes an emission layer, and wherein the organic layer includes the composition.

For example, the emission layer of the organic layer in the light-emitting device may include the composition.

According to yet another aspect, an electronic apparatus includes the light-emitting device.

### BRIEF DESCRIPTION OF THE DRAWING

The above and other aspects, features, and advantages of certain exemplary embodiments will be more apparent from the following detailed description taken in conjunction with the FIGURE, which is a schematic cross-sectional view showing a light-emitting device according to one or more embodiments.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Hereinafter, a work function or a highest occupied molecular orbital (HOMO) energy level is expressed as an absolute value from a vacuum level. In addition, when the work function or the HOMO energy level is referred to be “deep,” “high” or “large,” the work function or the HOMO energy level has a large absolute value based on “0 electron Volts (eV)” of the vacuum level, while when the work function or the HOMO energy level is referred to be “shallow,” “low,” or “small,” the work function or HOMO energy level has a small absolute value based on “0 eV” of the vacuum level.

An aspect provides a composition including a first compound and a second compound.

The first compound is an organometallic compound including platinum (Pt) and a tetradentate ligand bound thereto, and the second compound is an organometallic compound including iridium (Ir).

The first compound may include one Pt, and may not include any other metal than Pt.

The first compound may not include any other ligand than the tetradentate ligand bound to Pt.

The tetradentate ligand bound to Pt in the first compound may have excellent electrical properties and structural rigidity. In addition, the first compound including Pt and the tetradentate ligand bound thereto may have a planar structure, and in this regard, may have a relatively small dipole moment. Accordingly, a layer or a light-emitting device (e.g., an organic light-emitting device) employing the composition including the first compound may have excellent luminescence efficiency and a long lifespan.

The second compound may include one Ir, and may not include any other metal than Ir.

Each of the first compound and the second compound may be electrically neutral.

μ(Pt) is about 0.5 debye to about 5.0 debye, and μ(Pt) is less than μ(Ir). Here, μ(Pt) is a dipole moment of the first compound, and μ(Ir) is a dipole moment of the second compound.

As used herein, the terms “dipole moment of the first compound” and “dipole moment of the second compound” refer to “total permanent dipole moment in the molecule of the first compound” and “total permanent dipole moment in the molecule of the second compound”, respectively.

Each of μ(Pt) and μ(Ir) may be calculated based on density functional theory (DFT). Any various programs may be used for the quantum mechanical calculation based on the DFT, and for example, a Gaussian 16 program may be used. For example, each of μ(Pt) and μ(Ir) may be calculated using a density functional theory (DFT) method of a Gaussian program that is structurally optimized at a level of B3LYP/LanL2DZ for the metal (for example, platinum, iridium etc.) included in each of the first compound and the second compound and at a level of B3LYP/6-31G(D,P) for the organic ligand (for example, the tetradentate ligand, the bidentate ligand etc.) included in each of the first compound and the second compound.

For example, each of μ(Pt) and μ(Ir) may be calculated according to methods described in Evaluation Example 1.

Without wishing to be bound to theory, the composition including the first compound and the second compound in which μ(Pt) is about 0.5 debye to about 5.0 debye and μ(Pt) is less than μ(Ir) may have the following advantages:

1) in the composition, aggregation between molecules of the first compound, aggregation between molecules of the second compound, and/or aggregation between molecules of the first compound and molecules of the second compound are substantially minimized, so that the contents (e.g., weights) of the first compound and the second compound in the composition may be relatively increased without concern about aggregation between the molecules. Accordingly, a layer and a light-emitting device (e.g., an organic light-emitting device) employing the composition may have excellent luminescence efficiency and long lifespan characteristics; and

2) when an emission layer of a light-emitting device includes the composition, hole flux in the light-emitting layer is increased by the composition, so that an exciton recombination zone in the emission layer may be spaced apart from each of the interface between the emission layer and a hole transport region and the interface between the emission layer and an electron transport region, thereby improving lifespan characteristics.

In one or more embodiments, μ(Pt) may be about 1.5 debye to about 5.0 debye.

In one or more embodiments, μ(Pt) may be about 0.5 debye to about 3.0 debye, about 1.0 debye to about 3.0 debye, about 1.5 debye to about 3.0 debye, about 1.7 debye to about 3.0 debye, or about 1.7 debye to about 2.7 debye.

In one or more embodiments, μ(Pt) may be about 2.0 debye to about 5.0 debye, about 3.0 debye to about 5.0 debye, or about 4.0 debye to about 5.0 debye.

In one or more embodiments, μ(Ir) may be about 4.0 debye to about 9.0 debye, about 4.5 debye to about 7.5 debye, or about 5.0 debye to about 7.0 debye.

In one or more embodiments, μ(Ir)-μ(Pt) may be about 0.3 debye to about 4.0 debye.

In one or more embodiments, μ(Ir)-μ(Pt) may be about 2.0 debye to about 4.0 debye, or about 2.0 debye to about 3.0 debye.

In one or more embodiments, μ(Ir)-μ(Pt) may be about 0.3 debye to about 1.0 debye.

The first compound may emit a first light having a first spectrum, and λP(Pt) is an emission peak wavelength (nm) of the first spectrum.

The second compound may emit a second light having a second spectrum, and λP(Ir) is an emission peak wavelength (nm) of the second spectrum.

λP(Pt) may be evaluated from a photoluminescence spectrum measured for a first film, and λP(Ir) may be evaluated from a photoluminescence spectrum measured for a second film.

The term “first film” as used herein refers to a film including the first compound, and the term “second film” as used herein refers to a film including the second compound. The first film and the second film may be manufactured using any various methods, such as a vacuum deposition method, a coating and heating method, and the like. The first film and the second film may each independently further include a compound, for example, a host described herein, other than or in addition to the first compound and the second compound. As used herein, the term “emission peak wavelength” (also referred to as “peak emission wavelength” or “emission peak wavelength maximum”) refers to a wavelength in the emission peak at which the emission intensity is maximum.

For example, the evaluation method of λP(Pt) and λP(Ir) may be as described in Evaluation Example 2.

The absolute value of a difference between λP(Pt) and λP(Ir) may be 0 nanometers (nm) to about 30 nm, 0 nm to about 20 nm, or 0 nm to about 10 nm.

In one or more embodiments, λP(Pt) may be substantially the same as λP(Ir), or λP(Pt) may be equal to λP(Ir).

In one or more embodiments, λP(Pt) may be less than λP(Ir).

In one or more embodiments, λP(Pt) may be greater than λP(Ir).

In one or more embodiments, each of λP(Pt) and λP(Ir) may be about 510 nm to about 570 nm.

In one or more embodiments, each of λP(Pt) and λP(Ir) may be about 510 nm to about 540 nm.

In one or more embodiments, λP(Pt) may be about 510 nm to about 530 nm, and λP(Ir) may be about 520 nm to about 540 nm.

In one or more embodiments, each of λP(Pt) and λP(Ir) may be about 540 nm to about 570 nm.

In one or more embodiments, λP(Pt) may be about 540 nm to about 560 nm, and λP(Ir) may be about 550 nm to about 570 nm.

In one or more embodiments, each of the first light and the second light may be green light.

In one or more embodiments, the first light may be green light, and the second light may be yellowish-green light.

In one or more embodiments, each of the first light and the second light may be yellowish-green light.

In one or more embodiments, the first light may be yellowish-green light, and the second light may be yellow light.

In one or more embodiments, each of the first light and the second light may be yellow light.

In one or more embodiments, the first compound may be an organic compound including a) a chemical bond (e.g., a covalent bond) between a carbon atom of the tetradentate ligand and Pt, and b) a chemical bond (e.g., a covalent bond) between an oxygen atom of the tetradentate ligand and Pt. The first compound may further include a chemical bond (e.g., a coordinate bond) between a nitrogen atom of the tetradentate ligand and Pt.

In one or more embodiments, the first compound may be an organic compound including a) a chemical bond (e.g., a covalent bond) between a carbon atom of the tetradentate ligand and Pt, and b) a chemical bond (e.g., a covalent bond) between a sulfur atom of the tetradentate ligand and Pt. The first compound may further include a chemical bond (e.g., a coordinate bond) between a nitrogen atom of the tetradentate ligand and Pt.

In one or more embodiments, the second compound may include a first ligand, a second ligand, and a third ligand,

a) the first ligand, the second ligand, and the third ligand may be identical to each other, b) the first ligand and the second ligand may be identical to each other, and the second ligand and the third ligand may be different from each other, or c) the first ligand, the second ligand, and the third ligand may be different from each other, and

each of the first ligand, the second ligand, and the third ligand may include:

a bidentate ligand bound to Ir of the second compound via two nitrogen atoms;

a bidentate ligand bound to Ir of the second compound via a nitrogen atom and a carbon atom; or

a bidentate ligand bound to Ir of the second compound via two carbon atoms.

For example, each of the first ligand, the second ligand, and the third ligand may be a bidentate ligand bound to iridium of the second compound via a nitrogen atom and a carbon atom.

In one or more embodiments, the first compound may be an organometallic compound represented by Formula 1, and the second compound may be an organometallic compound represented by Formula 2:

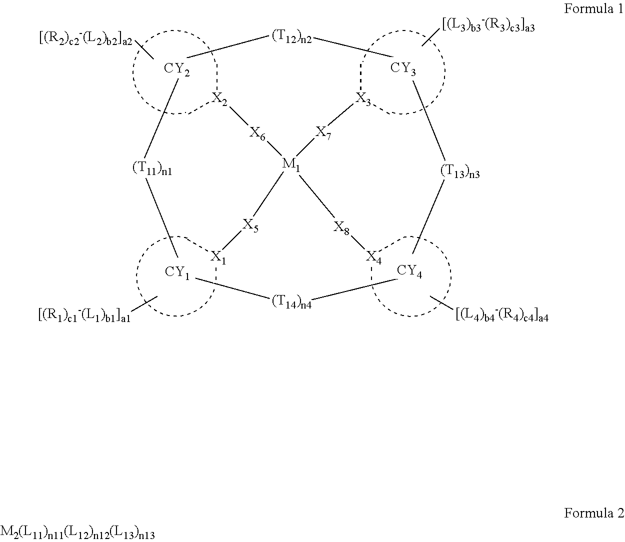

wherein M₁ in Formula 1 may be Pt, and M₂ in Formula 2 may be Ir.

In Formula 2, L₁₁ may be a ligand represented by Formula 2-1, L₁₂ may be a ligand represented by Formula 2-2, and L₁₃ may be a ligand represented by Formula 2-1 or 2-2:

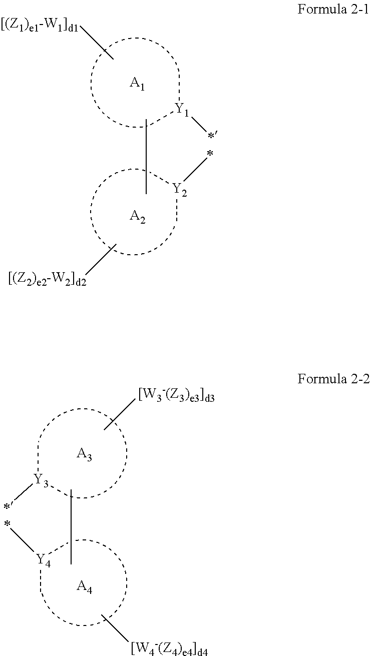

wherein Formulae 2-1 and 2-2 may be as described herein.

In Formula 2, L₁₁ and L₁₂ may be different from each other.

In Formula 2, n11 to n13 each indicates the number of L₁₁(s) to the number of L₁₃(s), respectively, and may each independently be 0, 1, 2, or 3, wherein a sum of n11+n12+n13 may be 3.

In one or more embodiments, in Formula 2, n11 may be 1, 2, or 3, and n12 and n13 may each independently be 0, 1, or 2.

In one or more embodiments, in Formula 2, n12 may be 1, 2, or 3, and n11 and n13 may each independently be 0, 1, or 2.

In one or more embodiments, n11 may be 1, n12 may be 2, and n13 may be 0.

In one or more embodiments, n11 may be 2, n12 may be 1, and n13 may be 0.

In one or more embodiments, n11 may be 3, and n12 and n13 may each be 0.

In one or more embodiments, n12 may be 3, and n11 and n13 may each be 0.

The second compound represented by Formula 2 may be a heteroleptic complex or a homoleptic complex.

For example, the second compound may be a heteroleptic complex.

In Formulae 1, 2-1, and 2-2, X₁ to X₄ and Y₁ to Y₄ may each independently be C or N.

In one or more embodiments, at least one of X₁ to X₄ in Formula 1 may be C.

In one or more embodiments, X₁ in Formula 1 may be C.

In one or more embodiments, in Formula 1, i) X₁ and X₃ may each be C, and X₂ and X₄ may each be N, or ii) X₁ and X₄ may each be C, and X₂ and X₃ may each be N.

In one or more embodiments, in Formulae 2-1 and 2-2, Y₁ and Y₃ may each be N, and Y₂ and Y₄ may each be C.

In Formula 1, X₅ to X₈ may each independently be a chemical bond, O, S, N(R′), C(R′)(R″), or C(═O), wherein at least one of X₅ to X₈ may not be a chemical bond. R′ and R″ may each be as described herein.

In one or more embodiments, X₅ in Formula 1 may not be a chemical bond.

In one or more embodiments, X₅ in Formula 1 may be O or S.

In one or more embodiments, in Formula 1, X₅ may be O or S, and X₆ to X₈ may each be a chemical bond.

In Formula 1, two bonds of a bond between X₅ or X₁ and M₁, a bond between X₆ or X₂ and M₁, a bond between X₇ or X₃ and M₁, and a bond between X₈ or X₄ and M₁ may each be a coordinate bond, and the other two bonds may each be a covalent bond.

For example, in Formula 1, a bond between X₂ and M may be a coordinate bond.

In one or more embodiments, in Formula 1, a bond between X₅ or X₁ and M and a bond between X₃ and M may each be a covalent bond, and a bond between X₂ and M and a bond between X₄ and M may each be a coordinate bond.

In one or more embodiments, the first compound and the second compound may each be electrically neutral.

In Formulae 1, 2-1, and 2-2, ring CY₁ to ring CY₄ and ring A₁ to ring A₄ may each independently be a C₅-C₃₀ carbocyclic group or a C₁-C₃₀ heterocyclic group.

For example, each of ring CY₁, ring CY₃, and ring CY₄ may not be a benzimidazole group.

For example, in Formulae 1, 2-1, and 2-2, ring CY₁ to ring CY₄ and ring A₁ to A₄ may each independently be i) a first ring, ii) a second ring, iii) a condensed ring in which two or more first rings are condensed with each other, iv) a condensed ring in which two or more second rings are condensed with each other, or v) a condensed ring in which one or more first rings and one or more second rings are condensed with each other,

wherein the first ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and

the second ring may be an adamantane group, a norbornane group, a norbornene group, a piperidine group, a cyclohexane group, a cyclohexene group, a benzene group, a pyridine group, a pyrimidine group, a pyrazine group, a pyridazine group, or a triazine group.

In one or more embodiments, in Formulae 1, 2-1, and 2-2, ring CY₁ to ring CY₄ and ring A₁ to ring A₄ may each independently be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, a pyrrole group, a furan group, a thiophene group, a silole group, a borole group, a phosphole group, a germole group, a selenophene group, an indene group, an indole group, a benzofuran group, a benzothiophene group, a benzosilole group, a benzoborole group, a benzophosphole group, a benzogermole group, a benzoselenophene group, a fluorene group, a carbazole group, a dibenzofuran group, a dibenzothiophene group, a dibenzosilole group, a dibenzoborole group, a dibenzophosphole group, a dibenzogermole group, a dibenzoselenophene group, a benzofluorene group, a benzocarbazole group, a naphthobenzofuran group, a naphthobenzothiophene group, a naphthobenzosilole group, a naphthobenzoborole group, a naphthobenzophosphole group, a naphthobenzogermole group, a naphthobenzoselenophene group, a dibenzofluorene group, a dibenzocarbazole group, a dinaphthofuran group, a dinaphthothiophene group, a dinaphthosilole group, a dinaphthoborole group, a dinaphthophosphole group, a dinaphthogermole group, a dinaphthoselenophene group, an indenophenanthrene group, an indolophenanthrene group, a phenanthrobenzofuran group, a phenanthrobenzothiophene group, a phenanthrobenzosilole group, a phenanthrobenzoborole group, a phenanthrobenzophosphole group, a phenanthrobenzogermole group, a phenanthrobenzoselenophene group, a dibenzothiophene 5-oxide group, a 9H-fluorene-9-one group, a dibenzothiophene 5,5-dioxide group, an azaindene group, an azaindole group, an azabenzofuran group, an azabenzothiophene group, an azabenzosilole group, an azabenzoborole group, an azabenzophosphole group, an azabenzogermole group, an azabenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenzosilole group, an azanaphthobenzoborole group, an azanaphthobenzophosphole group, an azanaphthobenzogermole group, an azanaphthobenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthrobenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, an azadibenzothiophene 5-oxide group, an aza9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a pyrrole group, a pyrazole group, imidazole group, a triazole group, an oxazole group, an isoxazole group, thiazole group, an isothiazole group, an oxadiazole group, a thiadiazole group, an azasilole group, an azaborole group, an azaphosphole group, an azagermole group, an azaselenophene group, a benzopyrrole group, a benzopyrazole group, a benzimidazole group, a benzoxazole group, a benzisoxazole group, a benzothiazole group, a benzisothiazole group, a benzoxadiazole group, a benzothiadiazole group, a pyridinopyrrole group, a pyridinopyrazole group, a pyridinoimidazole group, a pyridinooxazole group, a pyridinoisoxazole group, a pyridinothiazole group, a pyridinoisothiazole group, a pyridinooxadiazole group, a pyridinothiadiazole group, a pyrimidinopyrrole group, a pyrimidinopyrazole group, a pyrimidinoimidazole group, a pyrimidinoxazole group, a pyrimidinoisoxazole group, a pyrimidinothiazole group, a pyrimidinoisothiazole group, a pyrimidinooxadiazole group, a pyrimidinothiadiazole group, a naphthopyrrole group, a naphthopyrazole group, a naphthoimidazole group, a naphthoxazole group, a naphthoisoxazole group, a naphthothiazole group, a naphthoisothiazole group, a naphthoxadiazole group, a naphthothiadiazole group, a phenanthrenopyrrole group, a phenanthrenopyrazole group, a phenanthrenoimidazole group, a phenanthrenoxazole group, a phenanthrenoisoxazole group, a phenanthrenothiazole group, a phenanthrenoisothiazole group, a phenanthrenoxadiazole group, a phenanthrenothiadiazole group, a 5,6,7,8-tetrahydroisoquinoline group, a 5,6,7,8-tetrahydroquinoline group, an adamantane group, a norbornane group, a norbornene group, a benzene group condensed with a cyclohexane group, a benzene group condensed with a norbornane group, a pyridine group condensed with a cyclohexane group, or a pyridine group condensed with a norbornane group.

In one or more embodiments, ring CY₁ and ring CY₃ in Formula 1 may each independently be:

a benzene group, a naphthalene group, a phenanthrene group, a dibenzofuran group, a dibenzothiophene group, a dibenzoselenophene group, a carbazole group, a fluorene group, or a dibenzosilole group; or

a benzene group, a naphthalene group, a phenanthrene group, a dibenzofuran group, a dibenzothiophene group, a dibenzoselenophene group, a carbazole group, a fluorene group, or a dibenzosilole group, each condensed with at least one of a cyclohexane group, a cyclohexene group, a norbornane group, a piperidine group, or a combination thereof.

In one or more embodiments, ring CY₂ in Formula 1 may be:

an imidazole group, a benzimidazole group, a pyridine group, a pyrimidine group, a pyridazine group, a pyrazine group, a triazine group, a quinoline group, an isoquinoline group, a quinoxaline group, or a quinazoline group; or

an imidazole group, a benzimidazole group, a pyridine group, a pyrimidine group, a pyridazine group, a pyrazine group, a triazine group, a quinoline group, an isoquinoline group, a quinoxaline group, or a quinazoline group, each condensed with at least one of a cyclohexane group, a cyclohexene group, a norbornane group, a benzene group, a pyridine group, a pyrimidine group, or a combination thereof.

In one or more embodiments, ring CY₄ in Formula 1 may be:

a pyridine group, a pyrimidine group, a pyridazine group, a pyrazine group, a triazine group, a quinoline group, an isoquinoline group, a quinoxaline group, a quinazoline group, an azadibenzofuran group, an azadibenzothiophene group, an azadibenzoselenophene group, an azacarbazole group, an azafluorene group, or an azadibenzosilole group; or

a pyridine group, a pyrimidine group, a pyridazine group, a pyrazine group, a triazine group, a quinoline group, an isoquinoline group, a quinoxaline group, a quinazoline group, an azadibenzofuran group, an azadibenzothiophene group, an azadibenzoselenophene group, an azacarbazole group, an azafluorene group, or an azadibenzosilole group, each condensed with at least one of a cyclohexane group, a cyclohexene group, a norbornane group, a benzene group, a pyridine group, a pyrimidine group, or a combination thereof.

In Formulae 2-1 and 2-2, ring A₁ and ring A₃ may be different from each other.

In one or more embodiments, a Y₁-containing monocyclic group in ring A₁, a Y₂-containing monocyclic group in ring A₂, and Y₄-containing monocyclic group in ring A₄ may each be a 6-membered ring.

In one or more embodiments, a Y₃-containing monocyclic group in ring A₃ may be a 6-membered ring.

In one or more embodiments, a Y₃-containing monocyclic group in ring A₃ may be a 5-membered ring.

In one or more embodiments, a Y₁-containing monocyclic group in ring A₁ may be a 6-membered ring, and a Y₃-containing monocyclic group in ring A₃ may be a 5-membered ring.

In one or more embodiments, in Formulae 2-1 and 2-2, ring A₁ and ring A₃ may each independently be i) one of Group A, ii) a polycyclic group in which two or more of Group A are condensed with each other, or iii) a polycyclic group in which at least one of Group A and at least one of Group B are condensed with each other,

wherein Group A may include a pyridine group, a pyrimidine group, a pyridazine group, a pyrazine group, or a triazine group, and

wherein Group B may include a cyclohexane group, a cyclohexene group, a norbornane group, a benzene group, a furan group, a thiophene group, a selenophene group, a pyrrole group, a cyclopentadiene group, or silole group.

In one or more embodiments, in Formula 2-2, ring A₃ may be i) one of Group C, ii) a polycyclic group in which two or more of Group C are condensed with each other, or iii) a polycyclic group in which at least one of Group C and at least one of Group D are condensed with each other,

wherein Group C may include a pyrrole group, a pyrazole group, an imidazole group, a triazole group, an oxazole group, an isoxazole group, a thiazole group, or an isothiazole group, and

wherein Group D may include a cyclohexane group, a cyclohexene group, a norbornane group, a benzene group, a furan group, a thiophene group, a selenophene group, a cyclopentadiene group, a silole group, a pyridine group, a pyrimidine group, a pyridazine group, a pyrazine group, or a triazine group.

In one or more embodiments, ring A₁ in Formula 2-1 may be:

a pyridine group, a pyrimidine group, a pyridazine group, or a pyrazine group; or

a pyridine group, a pyrimidine group, a pyridazine group, or a pyrazine group, each condensed with at least one of a cyclohexane group, a norbornane group, a benzene group, or a combination thereof.

In one or more embodiments, ring A₃ in Formula 2-2 may be:

a pyridine group, a pyrimidine group, a pyridazine group, or a pyrazine group;

a pyridine group, a pyrimidine group, a pyridazine group, or a pyrazine group, each condensed with at least one of a cyclohexane group, a norbornane group, a benzene group, or a combination thereof; or

an imidazole group, a benzimidazole group, a naphthoimidazole group, a phenanthrenoimidazole group, a pyridoimidazole group, an oxazole group, a benzoxazole group, a naphthooxazole group, a phenanthrenoxazole group, a pyridooxazole group, a thiazole group, a benzothiazole group, a naphthothiazole group, a phenanthrenothiazole group, or a pyridothiazole group.

In one or more embodiments, in Formulae 2-1 and 2-2, ring A₂ and ring A₄ may be different from each other.

In one or more embodiments, in Formulae 2-1 and 2-2, ring A₂ and ring A₄ may each independently be i) one of Group E, ii) a polycyclic group in which two or more of Group E are condensed with each other, or iii) a polycyclic group in which at least one of Group E and at least one of Group F are condensed with each other,

wherein Group E may include a benzene group, a pyridine group, a pyrimidine group, a pyridazine group, a pyrazine group, or a triazine group, and

wherein Group F may include a furan group, a thiophene group, a selenophene group, a pyrrole group, a cyclopentadiene group, a silole group, a pyrazole group, an imidazole group, an oxazole group, a thiazole group, an isoxazole group, or an isothiazole group.

In one or more embodiments, in Formula 2-1, ring A₂ may be a polycyclic group in which two or more of Group E and at least one of Group F are condensed with each other.

In one or more embodiments, in Formula 2-2, ring A₄ may be a polycyclic group in which two or more of Group E and at least one of Group F may be condensed with each other.

In one or more embodiments, ring A₂ in Formula 2-1 may be:

a benzene group, a naphthalene group, a phenanthrene group, a dibenzofuran group, a dibenzothiophene group, a dibenzoselenophene group, a carbazole group, a fluorene group, or a dibenzosilole group; or

a benzene group, a naphthalene group, a phenanthrene group, a dibenzofuran group, a dibenzothiophene group, a dibenzoselenophene group, a carbazole group, a fluorene group, or a dibenzosilole group, each condensed with at least one of a cyclohexane group, a norbornane group, a benzene group, or a combination thereof.

In one or more embodiments, ring A₄ in Formula 2-2 may be:

a benzene group, a naphthalene group, a phenanthrene group, a dibenzofuran group, a dibenzothiophene group, a dibenzoselenophene group, a carbazole group, a fluorene group, a dibenzosilole group, an azadibenzofuran group, an azadibenzothiophene group, an azadibenzoselenophene group, an azacarbazole group, an azafluorene group, or a dibenzosilole group; or

a benzene group, a naphthalene group, a phenanthrene group, a dibenzofuran group, a dibenzothiophene group, a dibenzoselenophene group, a carbazole group, a fluorene group, a dibenzosilole group, an azadibenzofuran group, an azadibenzothiophene group, an azadibenzoselenophene group, an azacarbazole group, an azafluorene group, or a dibenzosilole group, each condensed with at least one of a benzene group, a pyridine group, a pyrimidine group, a pyridazine group, a pyrazine group, a cyclohexane group, a norbornane group, a furan group, a thiophene group, a selenophene group, a pyrrole group, a cyclopentadiene group, a silole group, a pyrazole group, an imidazole group, an oxazole group, a thiazole group, an isoxazole group, an isothiazole group, or a combination thereof.

In Formula 1, T₁₁ to T₁₄ may each independently be a single bond, a double bond, *—N(R₅ₐ)—*′, *—B(R₅ₐ)—*′, *—P(R₅ₐ)—*′, *—C(R₅ₐ)(R_{5b})—*′, *—Si(R₅ₐ)(R_{5b})—*′, *—Ge(R₅ₐ)(R_{5b})—*′, *—S—*′, *—Se—*′, *—O—*′, *—C(═O)—*′, *—S(═O)—*′, *—S(═O)₂—*′, *—C(R₅ₐ)═*′, *═C(R₅ₐ)—*′, *—C(R₅ₐ)═C(R_{5b})—*′, *—C(═S)—*′, *—C≡C—*′, a C₅-C₃₀ carbocyclic group that is unsubstituted or substituted with at least one R₁₀ₐ, or a C₁-C₃₀ heterocyclic group that is unsubstituted or substituted with at least one R₁₀ₐ.

For example, in Formula 1, each of T₁₁ and T₁₂ may be a single bond, and T₁₃ may be a single bond, *—N(R₅ₐ)—*′, *—B(R₅ₐ)—*′, *—P(R₅ₐ)—*′, *—C(R₅ₐ)(R_{5b})—*′, *—Si(R₅ₐ)(R_{5b})—*′, *—Ge(R₅ₐ)(R_{5b})—*′, or *—O—*′.

In Formula 1, n1 to n4 each indicate the number of T₁₁ to the number of T₁₄, and may each independently be 0 or 1, wherein three or more of n1 to n4 may each independently be 1. That is, the organometallic compound represented by Formula 1 may have a tetradentate ligand.

In Formula 1, when n1 is 0, T₁₁ does not exist (that is, ring CY₁ and ring CY₂ are not linked to each other), when n2 is 0, T₁₂ does not exist (that is, ring CY₂ and ring CY₃ are not linked to each other), when n3 is 0, T₁₃ does not exist (that is, ring CY₃ and ring CY₄ are not linked to each other), and when n4 is 0, T₁₄ does not exist (that is, ring CY₄ and ring CY₁ are not linked to each other).

In one or more embodiments, in Formula 1, n1 to n3 may each be 1, and n4 may be 0.

In one or more embodiments, in Formulae 1, 2-1, and 2-2, L₁ to L₄ and W₁ to W₄ may each independently be a single bond, a C₁-C₂₀ alkylene group that is unsubstituted or substituted with at least one R₁₀ₐ, a C₅-C₃₀ carbocyclic group that is unsubstituted or substituted with at least one R₁₀ₐ, or a C₁-C₃₀ heterocyclic group that is unsubstituted or substituted with at least one R₁₀ₐ.

In one or more embodiments, in Formulae 1, 2-1, and 2-2, L₁ to L₄ and W₁ to W₄ may each independently be:

a single bond; or

a C₁-C₂₀ alkylene group, a cyclopentene group, a cyclohexane group, a cyclohexene group, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an iso-oxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, an adamantane group, a norbornane group, or a norbornene group, each unsubstituted or substituted with at least one R₁₀ₐ.

In one or more embodiments, in Formulae 1, 2-1, and 2-2, L₁ to L₄ and W₁ to W₄ may each independently be:

a single bond; or

a benzene group, a naphthalene group, a pyridine group, a fluorene group, a carbazole group, a dibenzofuran group, or a dibenzothiophene group, each unsubstituted or substituted with at least one R₁₀ₐ.

In one or more embodiments, in Formulae 1, 2-1, and 2-2, L₁ to L₄ and W₁ to W₄ may each independently be:

a single bond; or

a C₁-C₂₀ alkylene group, a benzene group, a naphthalene group, a dibenzofuran group, or a dibenzothiophene group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, or a combination thereof.

In Formula 1, b1 to b4 indicate the number of L₁(s) to the number of L₄(s), respectively, and may each independently be an integer from 1 to 10. When b1 is 2 or more, two or more of L₁(s) may be identical to or different from each other, when b2 is 2 or more, two or more of L₂(s) may be identical to or different from each other, when b3 is 2 or more, two or more of L₃(s) may be identical to or different from each other, and when b4 is 2 or more, two or more of L₄(s) may be identical to or different from each other. For example, b1 to b4 may each independently be 1, 2, or 3.

In Formulae 1, 2-1, and 2-2, R₁ to R₄, R₅ₐ, R_{5b}, R′, R″, and Z₁ to Z₄ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉). Q₁ to Q₉ may each be as described herein.

In Formulae 1, 2-1, and 2-2, R₁ to R₄, R₅ₐ, R_{5b}, R, R″, and Z₁ to Z₄ may each independently be:

hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₁-C₂₀ alkoxy group, or a C₁-C₂₀ alkylthio group;

a C₁-C₂₀ alkyl group, a C₂-C₂₀ alkenyl group, a C₁-C₂₀ alkoxy group, or a C₁-C₂₀ alkylthio group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group (i.e., a bicyclo[2.2.1]heptyl group), a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or a combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with at least one of deuterium, —F, —Cl, —Br, —I, —SF₅, -CD₃, -CD₂H, -CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterated C₁-C₂₀ alkyl group, a fluorinated alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a deuterated phenyl group, a fluorinated phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or

—N(Q₁)(Q₂), —Si(Q₃)(Q₄)(Q₅), —Ge(Q₃)(Q₄)(Q₅), —B(Q₈)(Q₇), —P(═O)(Q₈)(Q₉), or —P(Q₈)(Q₉), and

Q₁ to Q₉ may each independently be:

deuterium, —F, —CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, —CF₃, —CF₂H, —CFH₂, —CH₂CF₃, —CH₂CF₂H, —CH₂CFH₂, —CHFCH₃, —CHFCF₂H, —CHFCFH₂, —CHFCF₃, —CF₂CF₃, —CF₂CF₂H, or —CF₂CFH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, —F, a C₁-C₁₀ alkyl group, a phenyl group, or a combination thereof.

In one or more embodiments, in Formulae 1, 2-1, and 2-2, R₁ to R₄, R₅ₐ, R_{5b}, R, R″, and Z₁ to Z₄ may each independently be:

hydrogen, deuterium, —F, or a cyano group;

a C₁-C₂₀ alkyl group unsubstituted or substituted with at least one of deuterium, —F, a cyano group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated heterocycloalkyl group, a fluorinated C₁-C₁₀ heterocycloalkyl group, a (C₁-C₂₀ heterocycloalkyl group, a phenyl group, a deuterated a phenyl group, a fluorinated a phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or a combination thereof;

a C₃-C₁₀ cycloalkyl group, a C₁-C₁₀ heterocycloalkyl group, a phenyl group, a biphenyl group, a naphthyl group, a pyridinyl group, a fluorenyl group, a carbazolyl group, a dibenzofuranyl, or a dibenzothiophenyl group, each unsubstituted or substituted with at least one of deuterium, —F, a cyano group, a C₁-C₂₀ alkyl group, a deuterated C₁-C₂₀ alkyl group, fluorinated C₁-C₂₀ alkyl group, a C₁-C₂₀ alkoxy group, a deuterated alkoxy group, a fluorinated C₁-C₂₀ alkoxy group, a C₁-C₂₀ alkylthio group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated heterocycloalkyl group, a fluorinated C₁-C₁₀ heterocycloalkyl group, a (C₁-C₂₀ heterocycloalkyl group, a phenyl group, a deuterated phenyl group, a fluorinated a phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or a combination thereof; or

—Si(Q₃)(Q₄)(Q₅) or —Ge(Q₃)(Q₄)(Q₅).

In one or more embodiments, in Formula 2-1, each of e1 and d1 may not be 0, and at least one of a plurality of Z₁(s) may be a deuterated C₁-C₂₀ alkyl group, —Si(Q₃)(Q₄)(Q₅), or —Ge(Q₃)(Q₄)(Q₅). Q₃ to Q₅ may each be as described herein.

In one or more embodiments, Q₃ to Q₅ may each independently be:

a C₁-C₆₀ alkyl group unsubstituted or substituted with at least one of deuterium, a C₁-C₆₀ alkyl group, a C₆-C₆₀ aryl group, or a combination thereof; or

a C₆-C₆₀ aryl group unsubstituted or substituted with at least one of deuterium, a C₁-C₆₀ alkyl group, a C₆-C₆₀ aryl group, or a combination thereof.

In one or more embodiments, Q₃ to Q₅ may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, a C₁-C₁₀ alkyl group, a phenyl group, or a combination thereof.

In one or more embodiments, Q₃ to Q₅ may be identical to each other.

In one or more embodiments, two or more of Q₃ to Q₅ may be different from each other.

In one or more embodiments, the second compound may satisfy at least one of Condition (1) to Condition (8):

Condition (1)

Each of e1 and d1 in Formula 2-1 is not 0, and at least one Z₁ includes deuterium;

Condition (2)

Each of e2 and d2 in Formula 2-1 is not 0, and at least one Z₂ includes deuterium;

Condition (3)

Each of e3 and d3 in Formula 2-2 is not 0, and at least one Z₃ includes deuterium;

Condition (4)

Each of e4 and d4 in Formula 2-2 is not 0, and at least one Z₄ includes deuterium;

Condition (5)

Each of e1 and d1 in Formula 2-1 is not 0, and at least one Z₁ includes a fluoro group;

Condition (6)

Each of e2 and d2 in Formula 2-1 is not 0, and at least one Z₂ includes a fluoro group;

Condition (7)

Each of e3 and d3 in Formula 2-2 is not 0, and at least one Z₃ includes a fluoro group; and

Condition (8)

Each of e4 and d4 in Formula 2-2 is not 0, and at least one Z₄ includes a fluoro group.

In one or more embodiments, in Formulae 1, 2-1, and 2-2, R₁ to R₄, R₅ₐ, R_{5b}, R, R″, and Z₁ to Z₄ may each independently be hydrogen, deuterium, —F, —CH₃, —CD₃, —CD₂H, —CDH₂, —CF₃, —CF₂H, —CFH₂, a C₂-C₁₀ alkenyl group, a C₁-C₁₀ alkoxy group, a C₁-C₁₀ alkylthio group, a group represented by one of Formulae 9-1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-227, a group represented by one of Formulae 9-201 to 9-227 in which at least one hydrogen is substituted with deuterium, a group represented by one of Formulae 9-201 to 9-227 in which at least one hydrogen is substituted with —F, a group represented by one of Formulae 10-1 to 10-129, a group represented by one of Formulae 10-1 to 10-129 in which at least one hydrogen is substituted with deuterium, a group represented by one of Formulae 10-1 to 10-129 in which at least one hydrogen is substituted with —F, a group represented by one of Formulae 10-201 to 10-350, a group represented by one of Formulae 10-201 to 10-350 in which at least one hydrogen is substituted with deuterium, a group represented by one of Formulae 10-201 to 10-350 in which at least one hydrogen is substituted with —F, —Si(Q₃)(Q₄)(Q₅), or —Ge(Q₃)(Q₄)(Q₅) (Q₃ to Q₅ may each be as described herein):

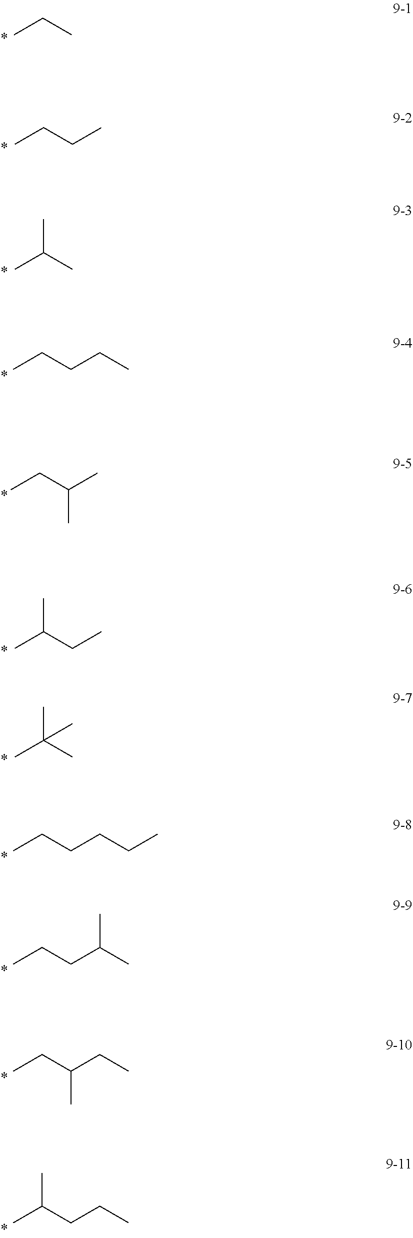

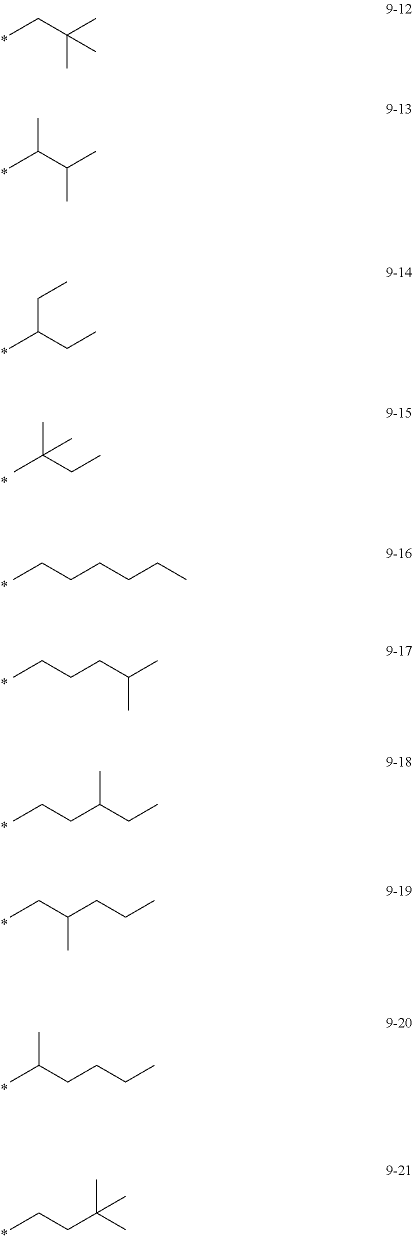

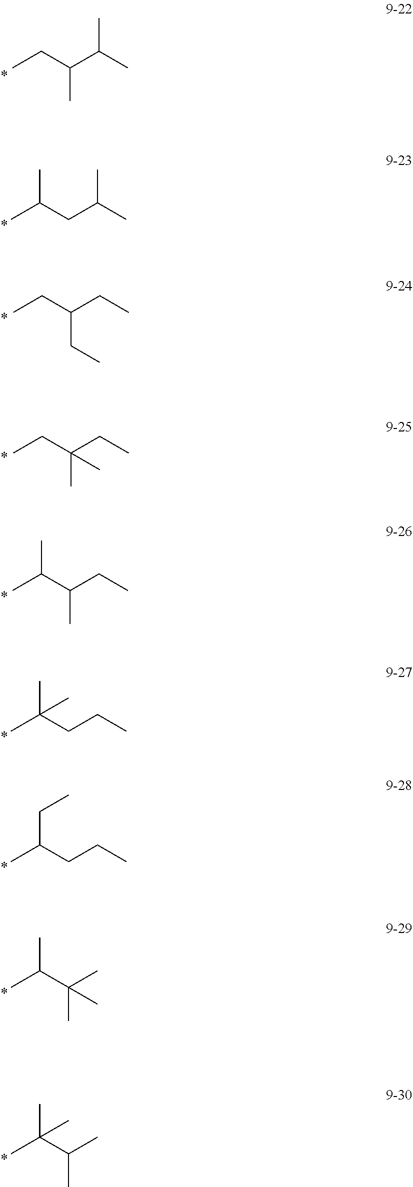

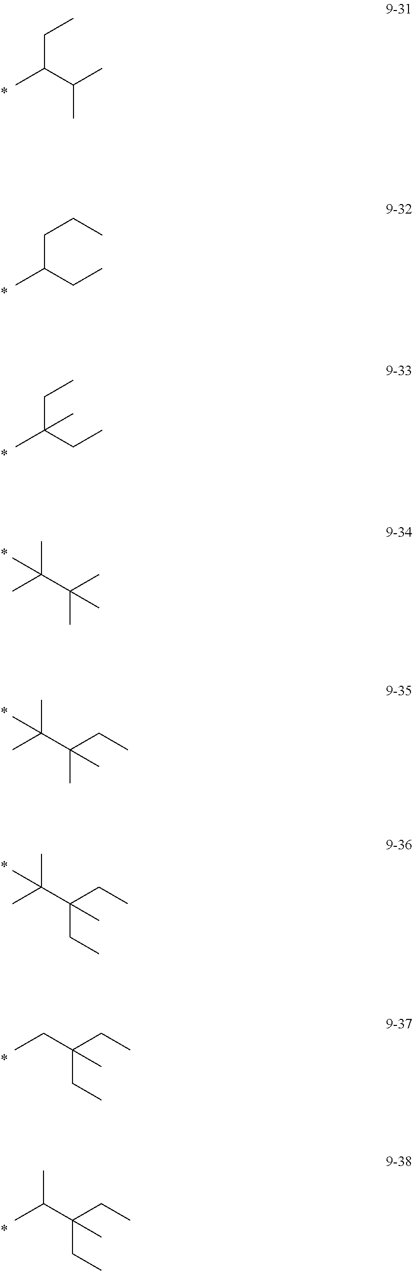

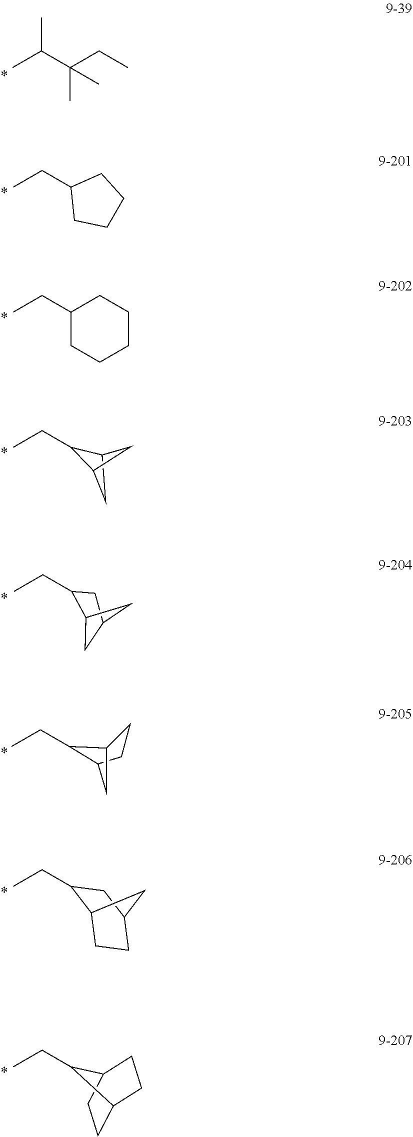

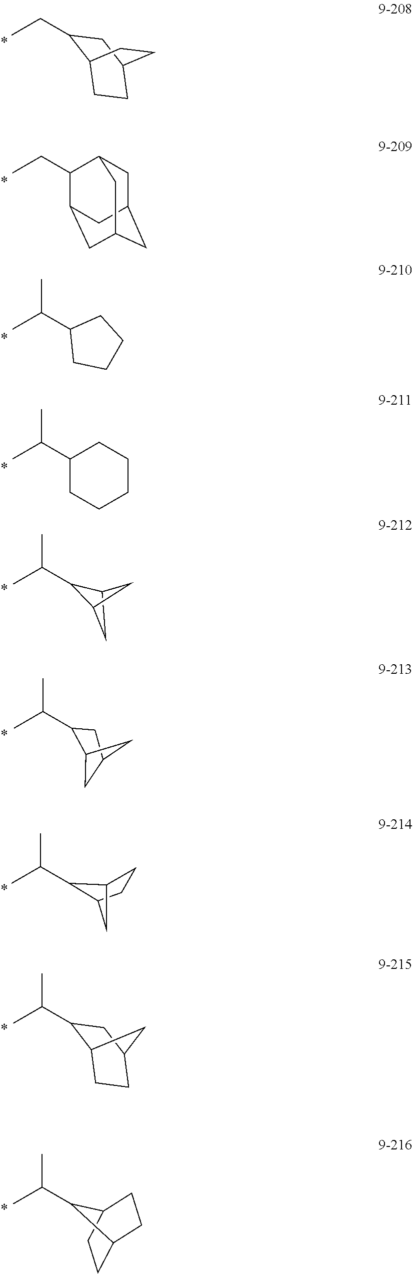

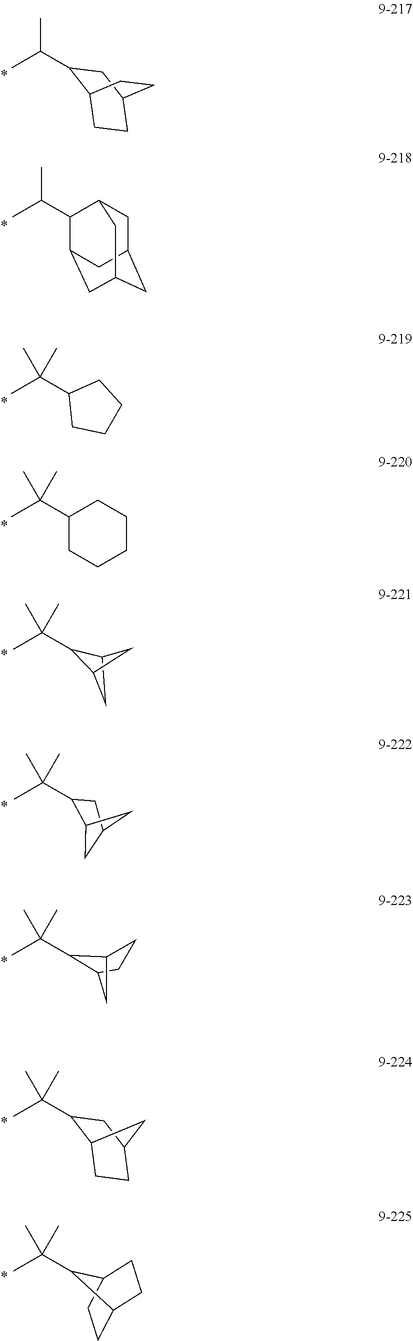

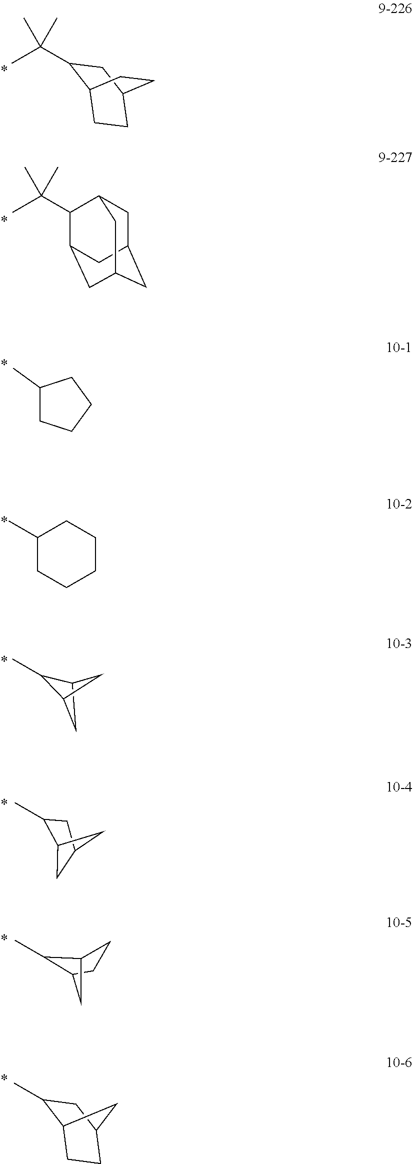

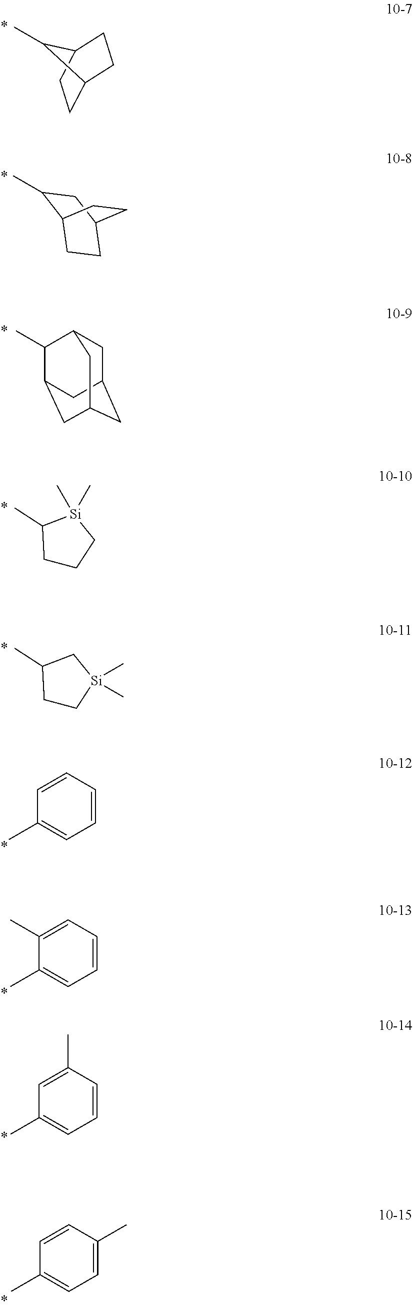

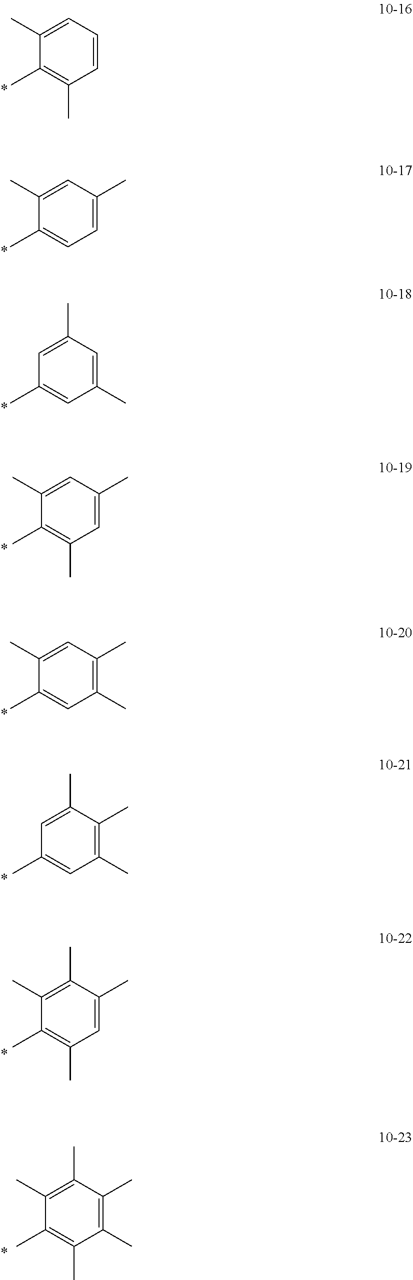

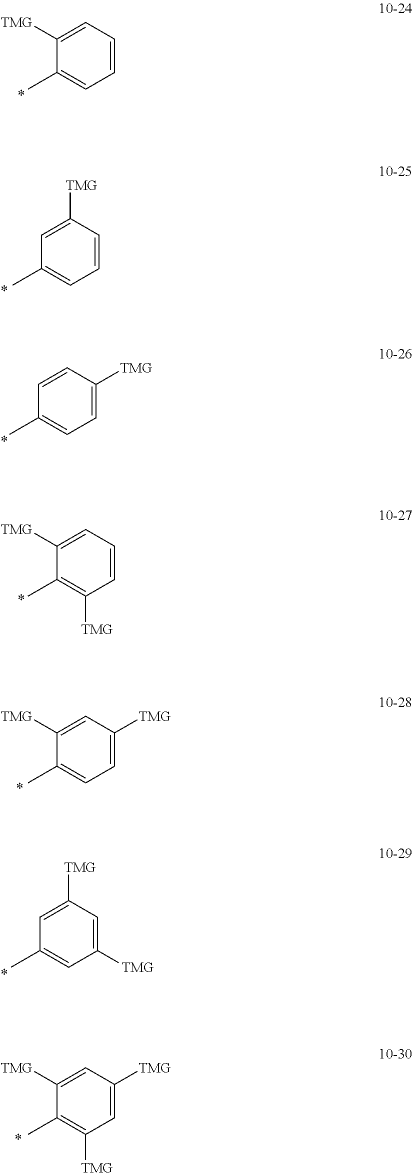

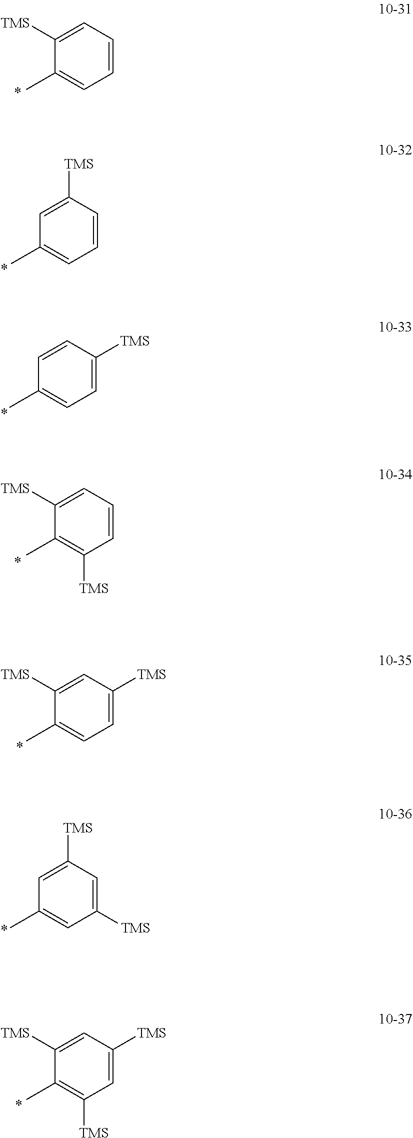

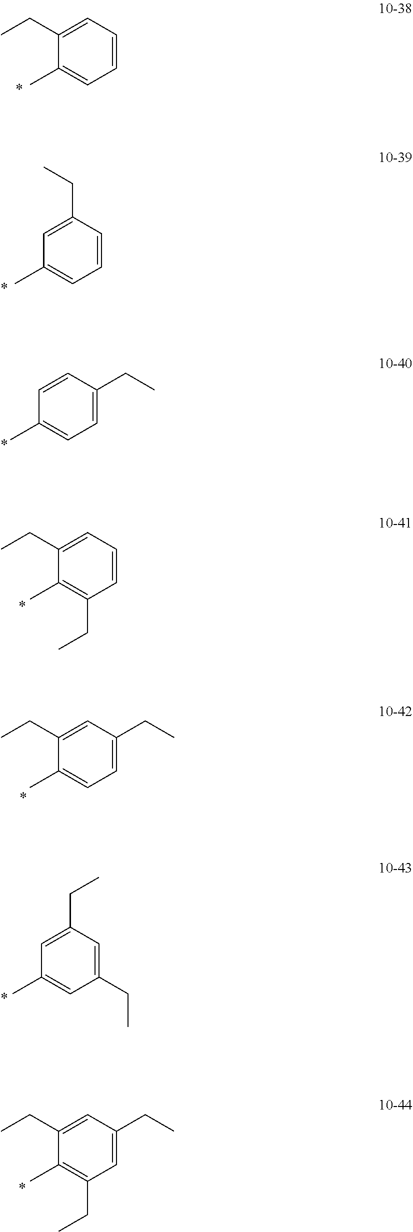

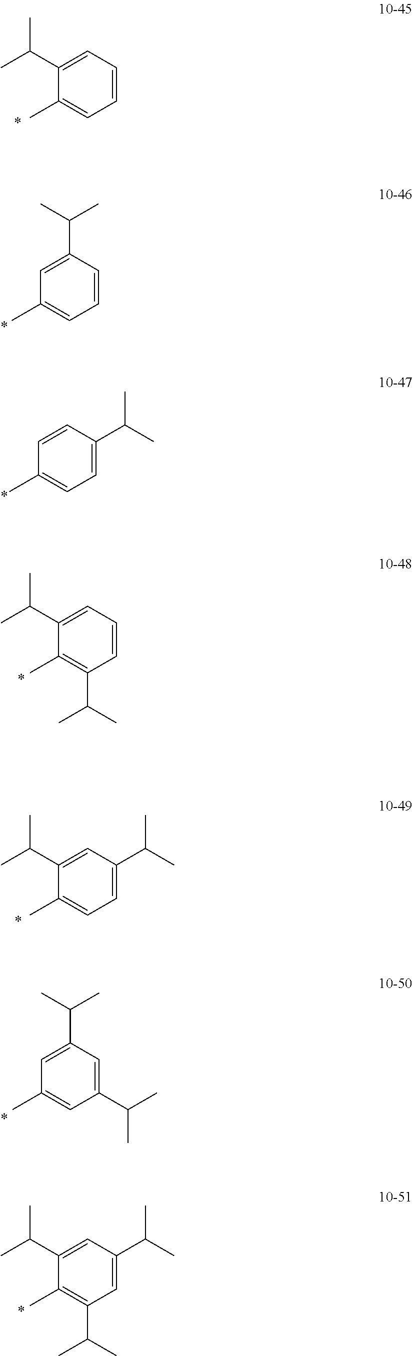

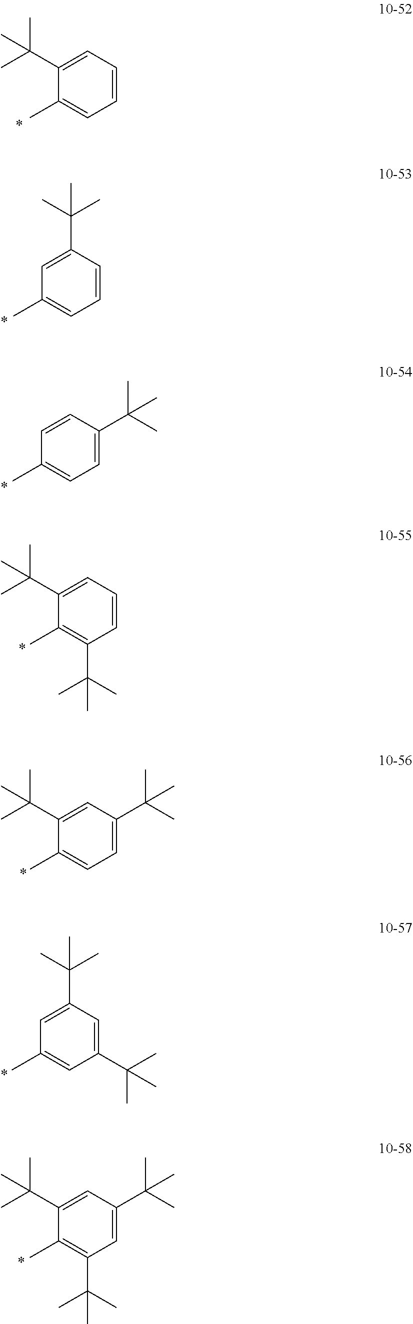

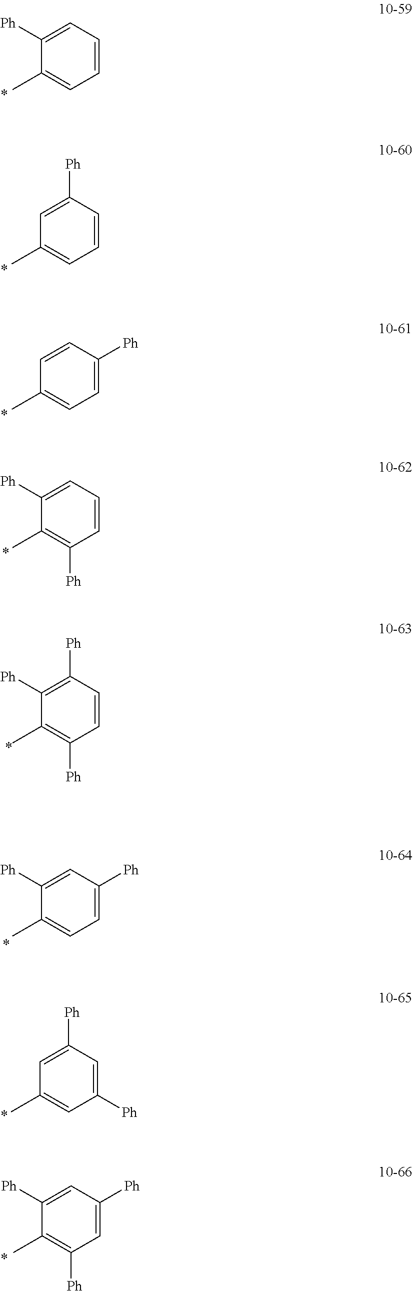

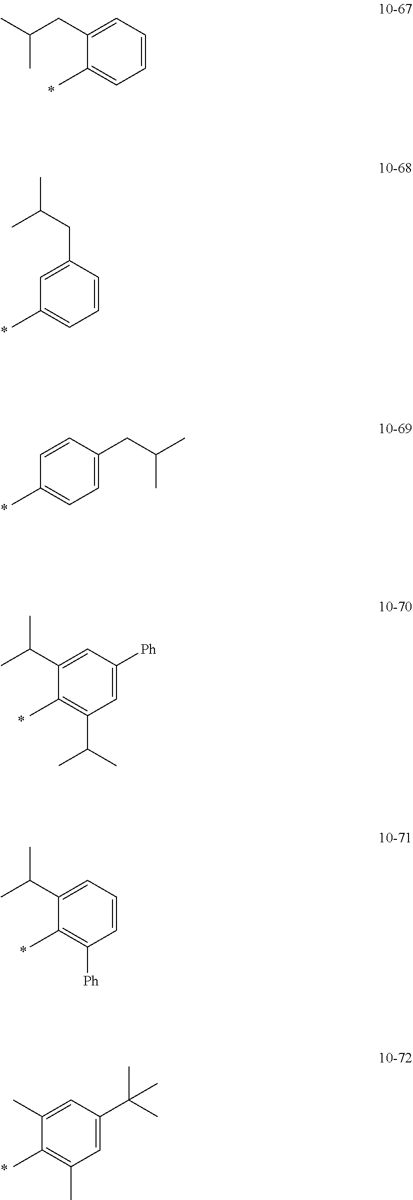

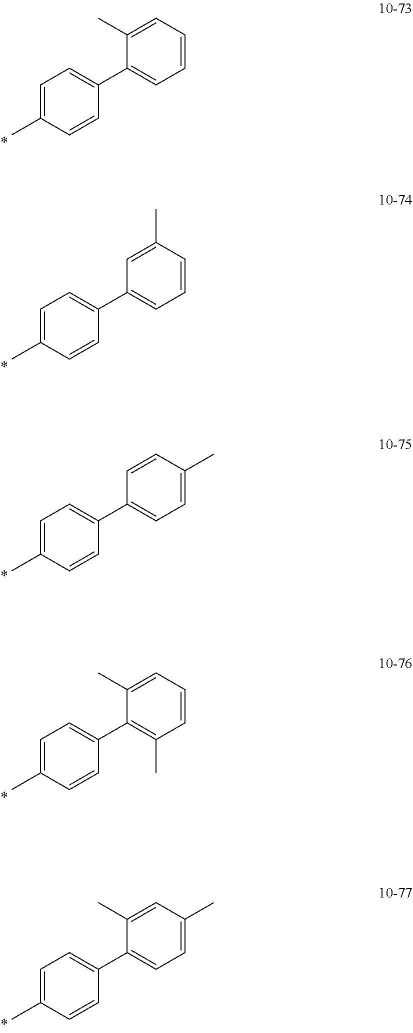

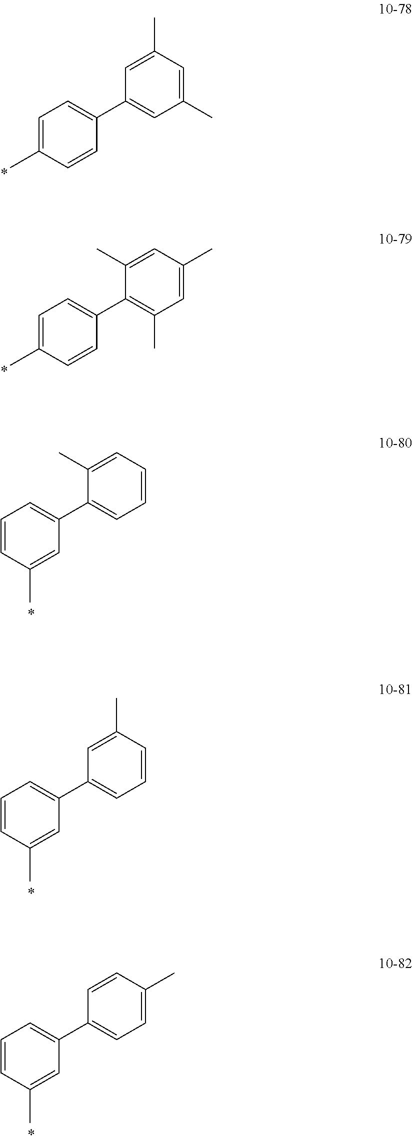

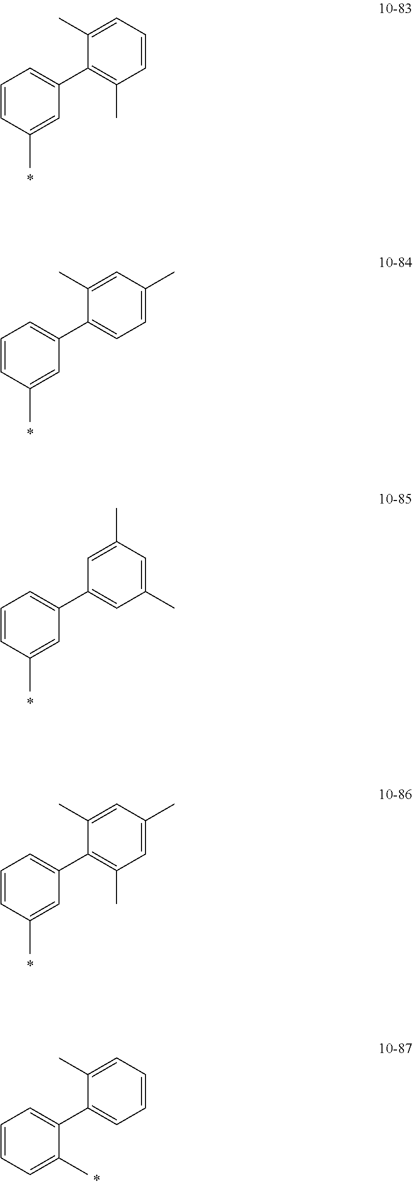

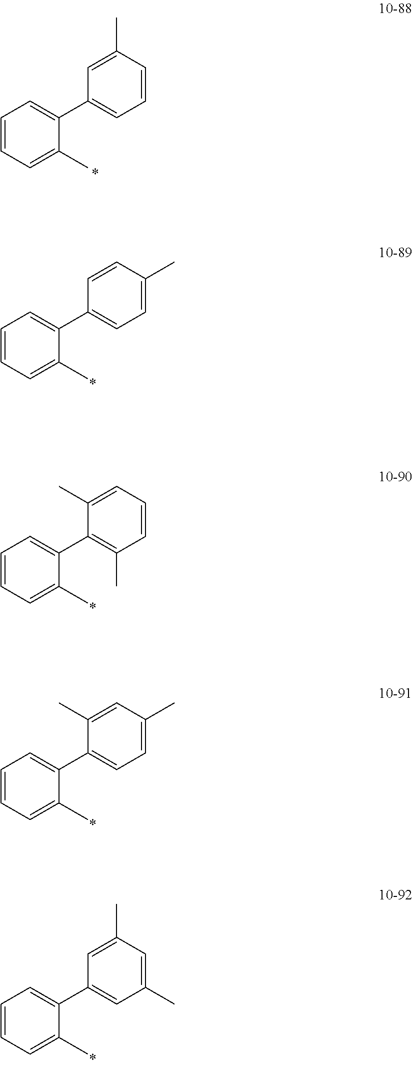

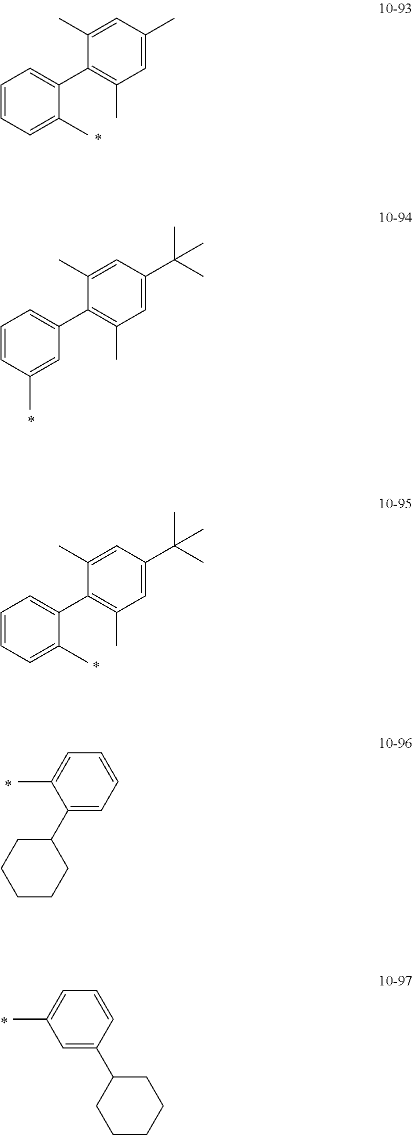

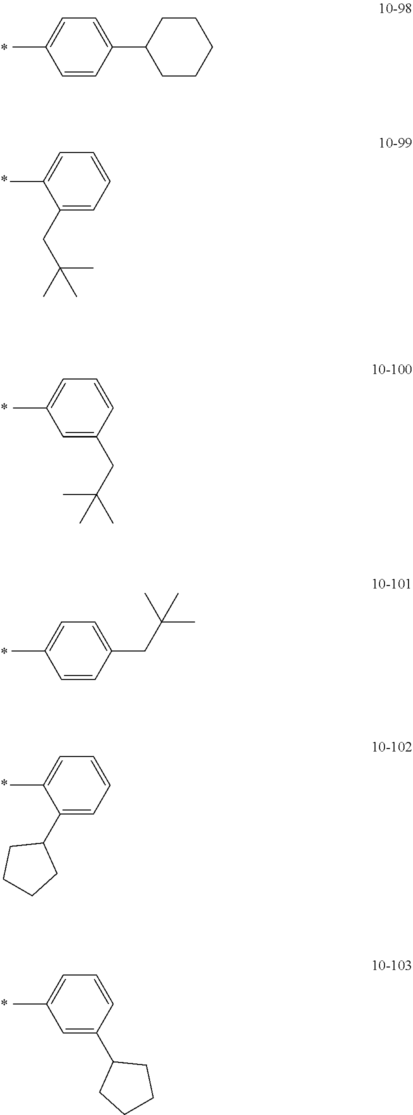

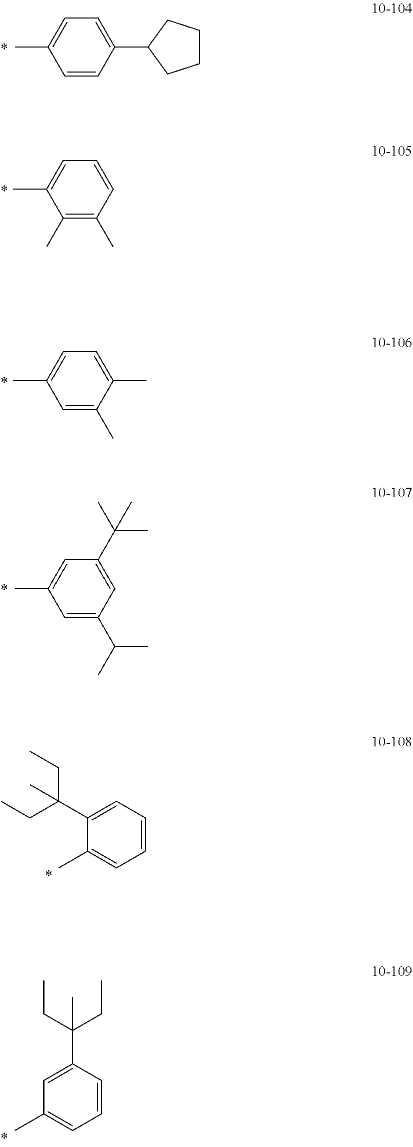

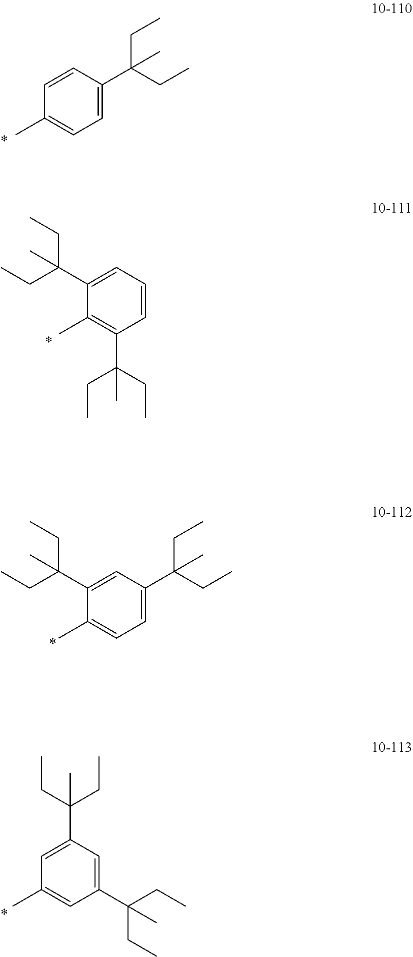

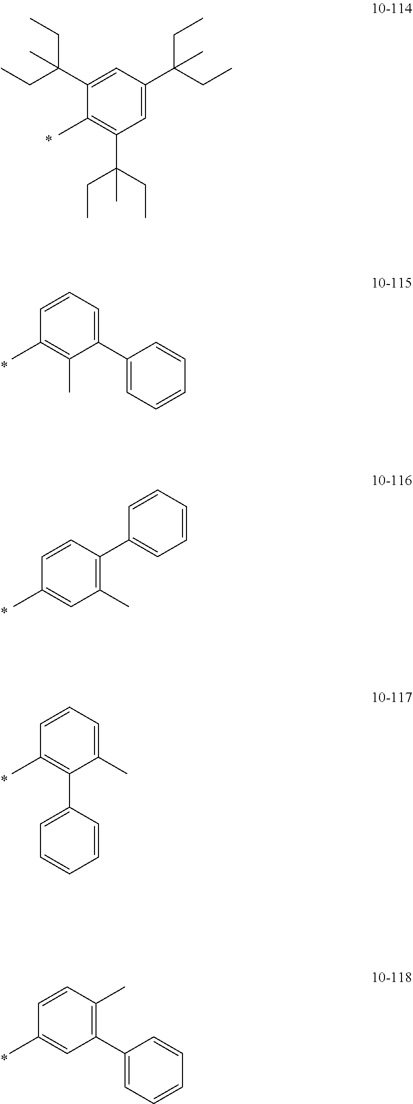

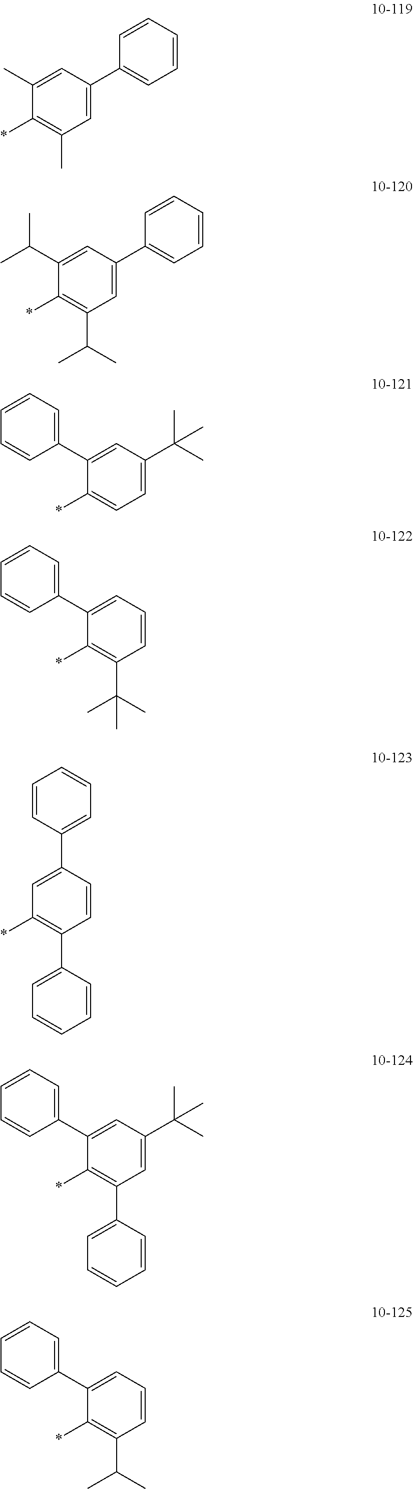

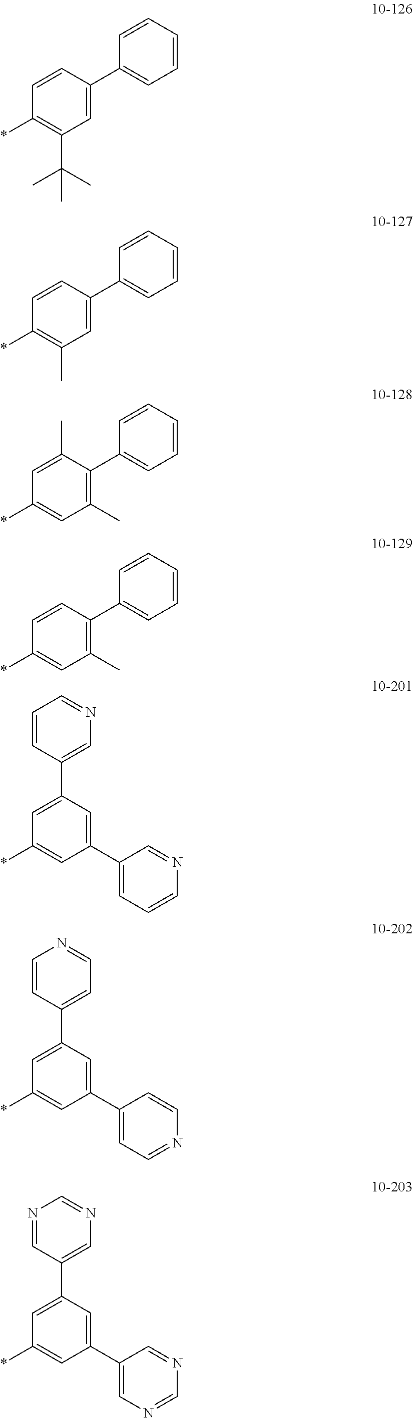

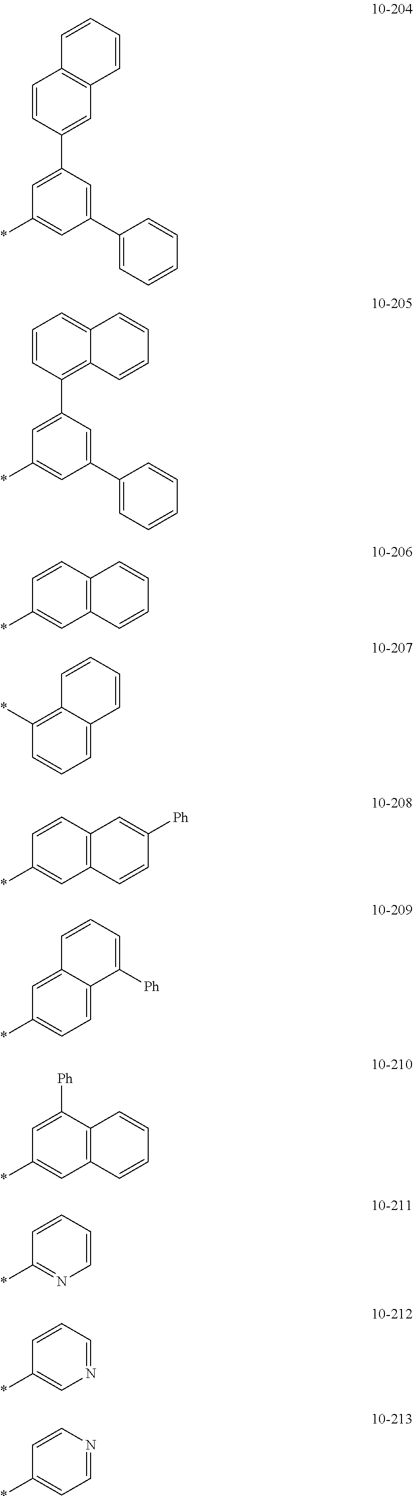

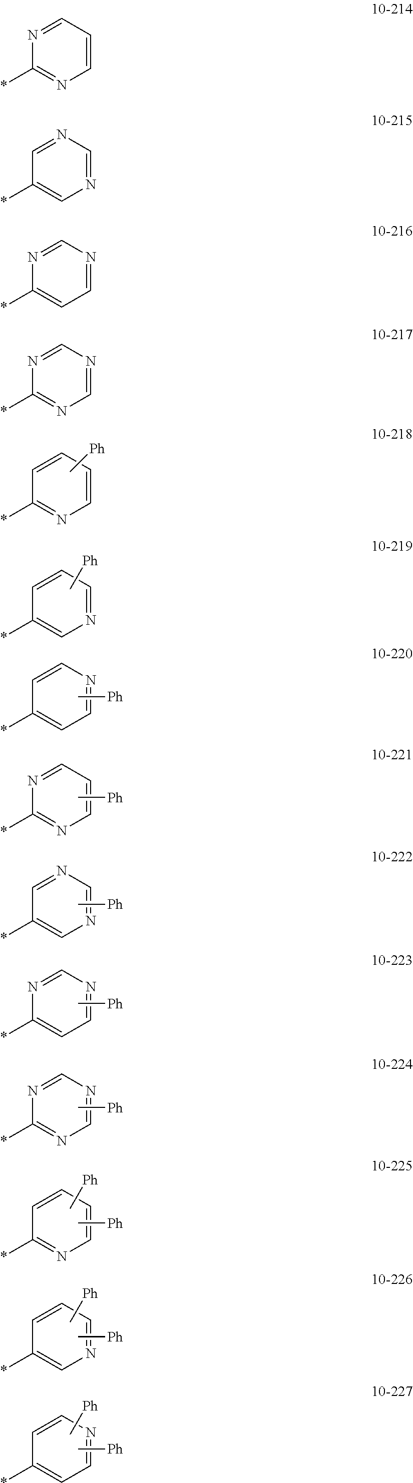

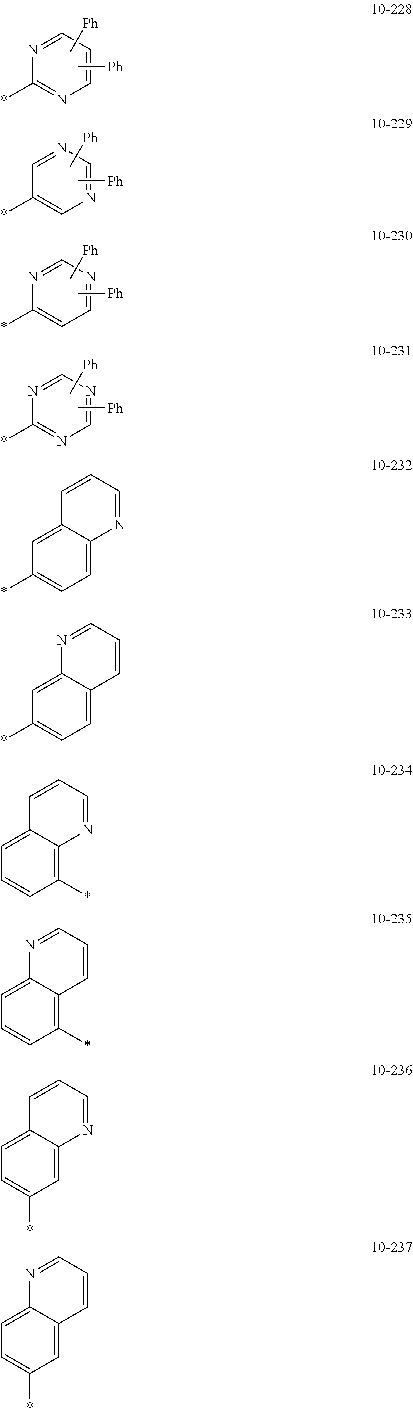

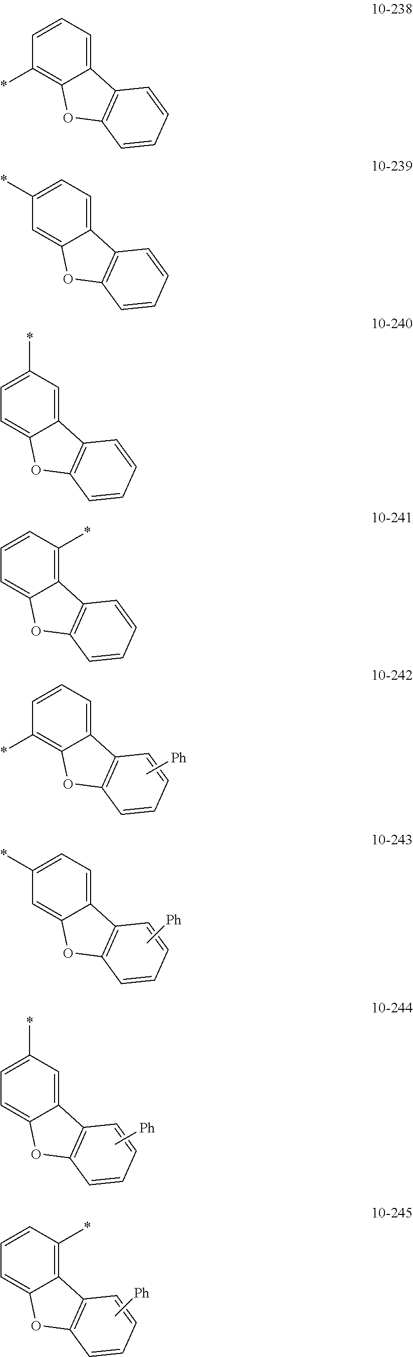

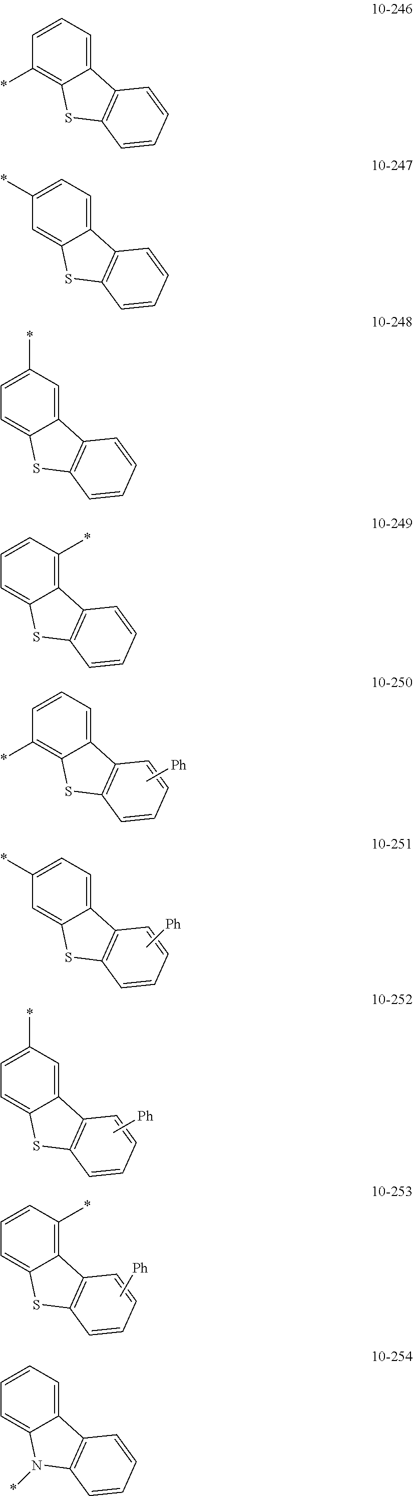

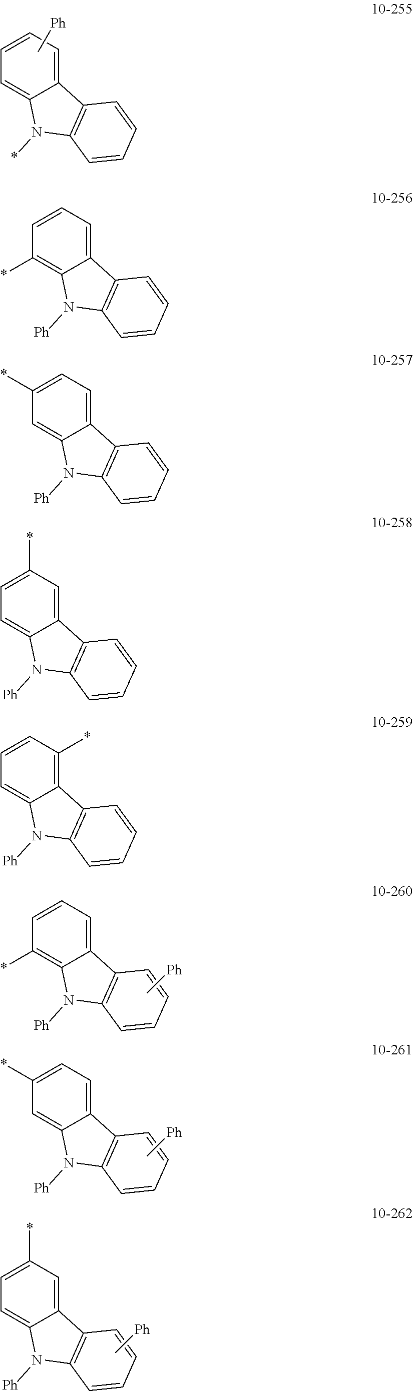

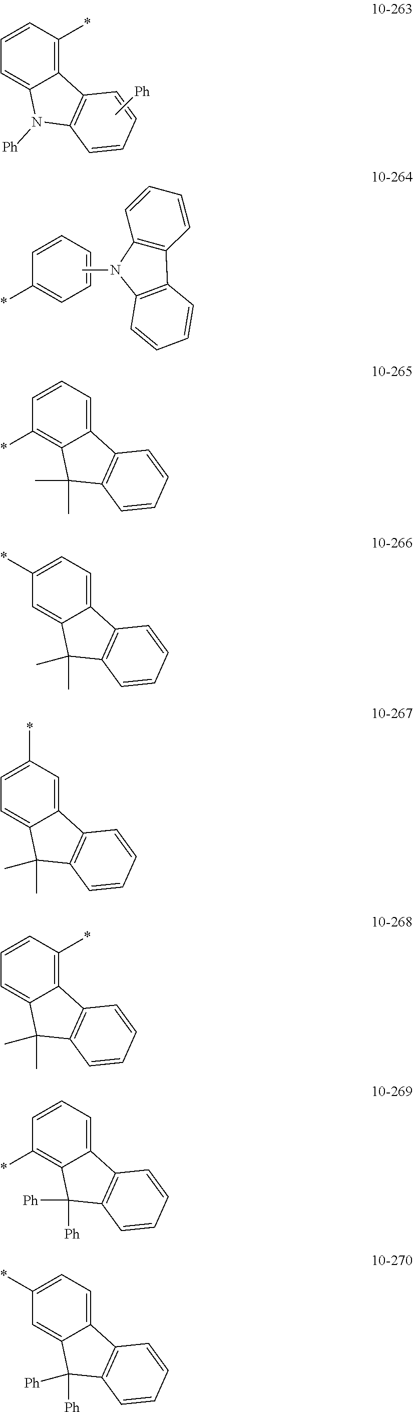

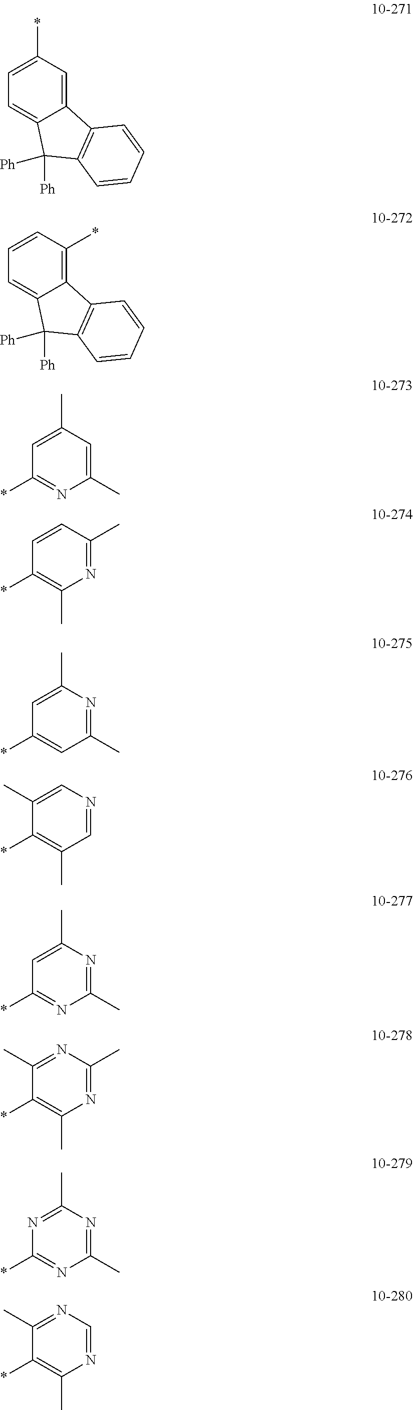

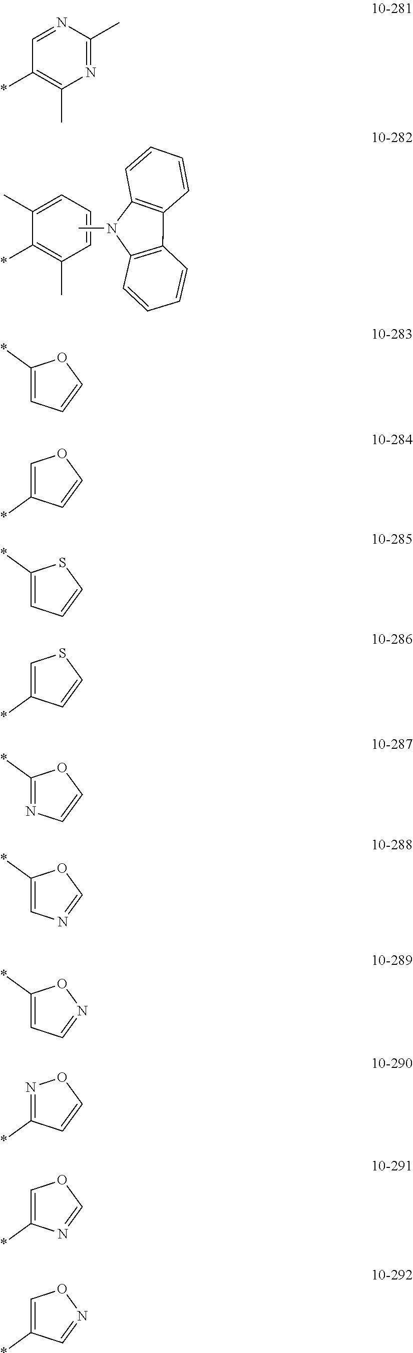

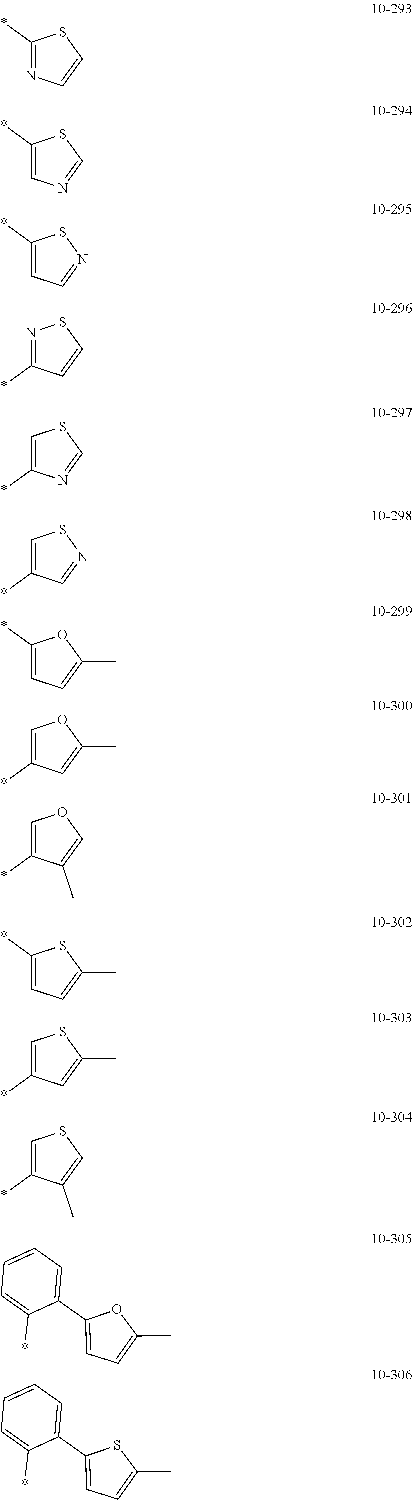

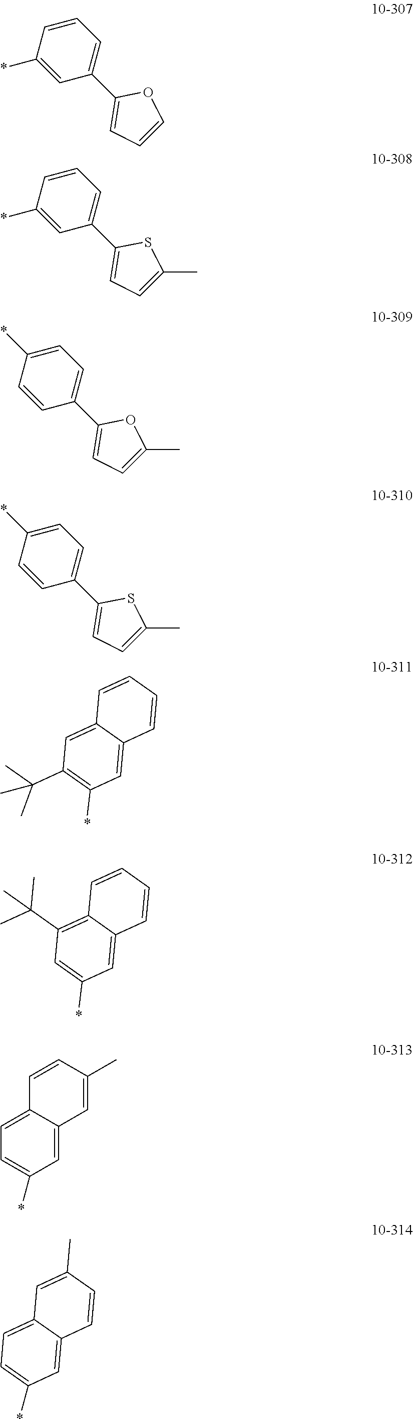

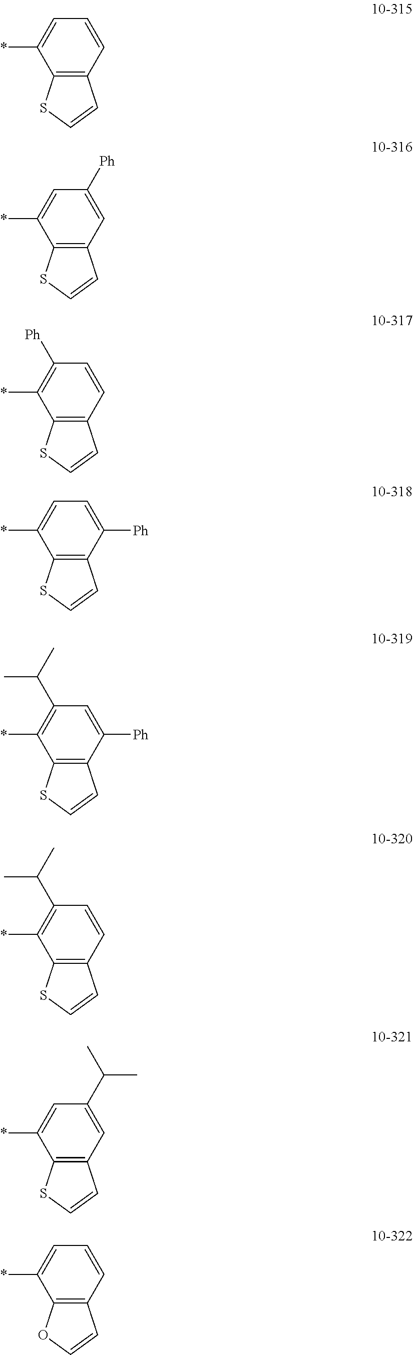

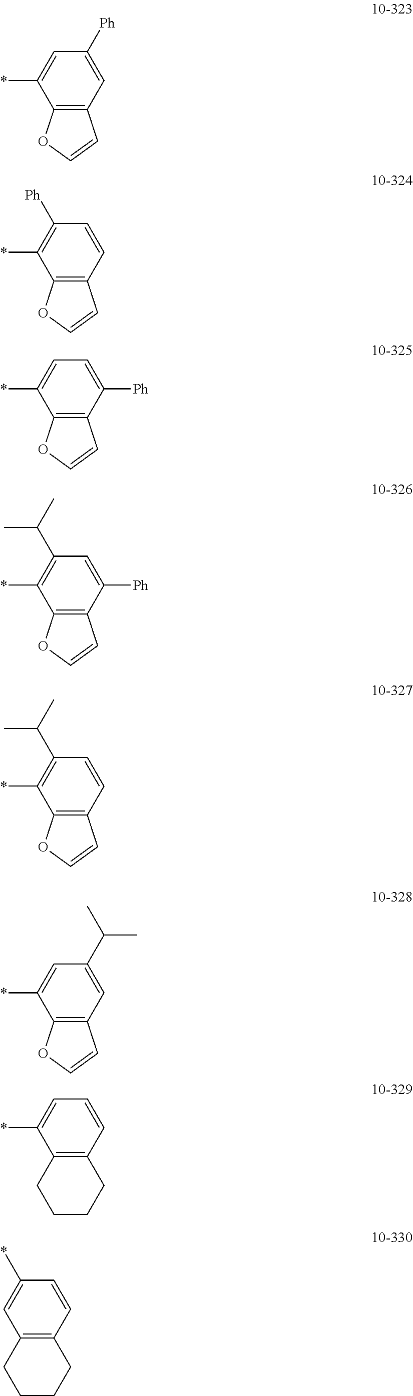

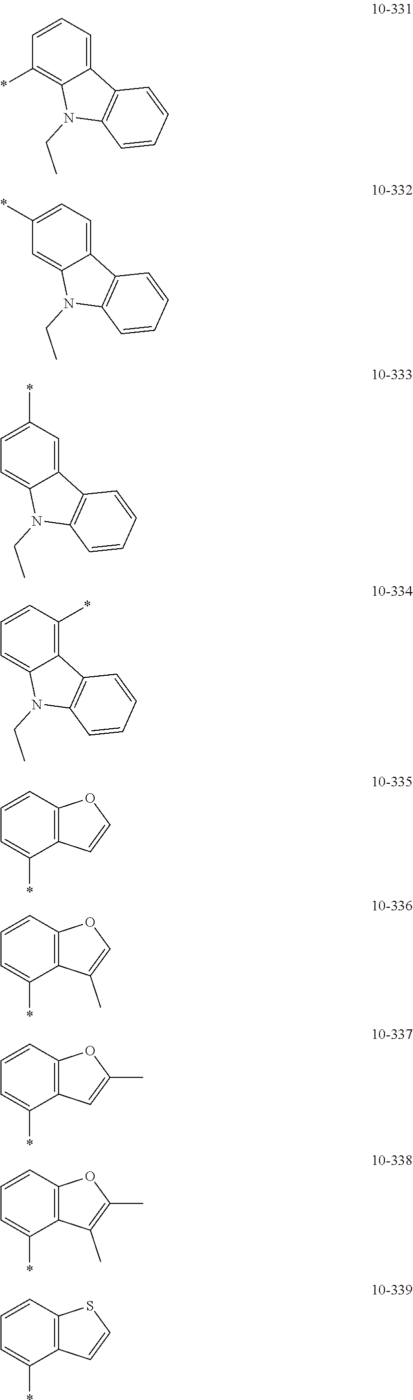

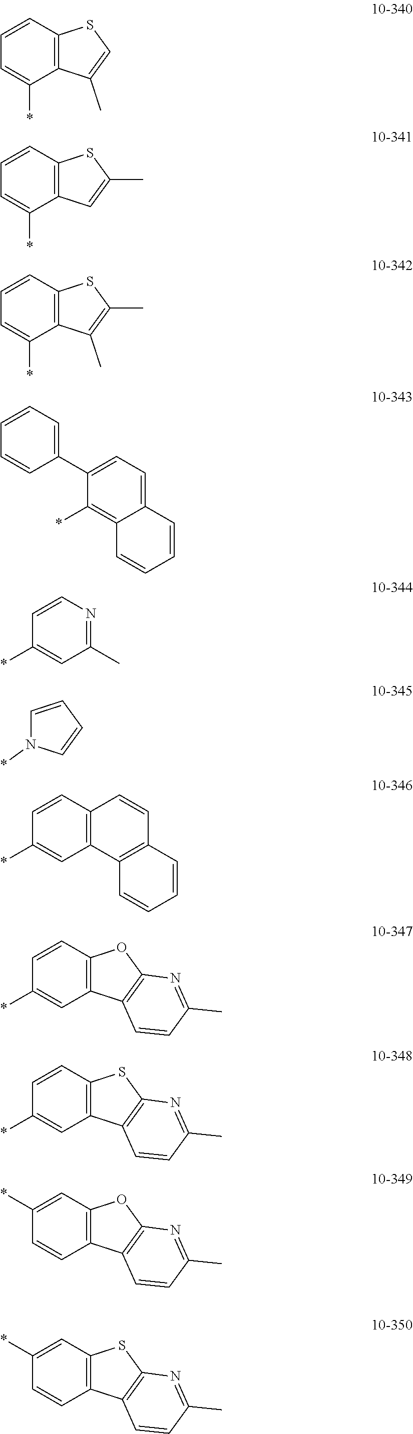

In Formulae 9-1 to 9-39, 9-201 to 9-237, 10-1 to 10-129, and 10-201 to 10-350, * indicates a binding site to a neighboring atom, “Ph” is a phenyl group, “TMS” is a trimethylsilyl group, and “TMG” is a trimethylgermyl group.

The “group represented by one of Formulae 9-1 to 9-39 in which at least one hydrogen is substituted with deuterium” and the “group represented by one of Formulae 9-201 to 9-237 in which at least one hydrogen is substituted with deuterium” may each be, for example, a group represented by one of Formulae 9-501 to 9-514 or 9-601 to 9-636:

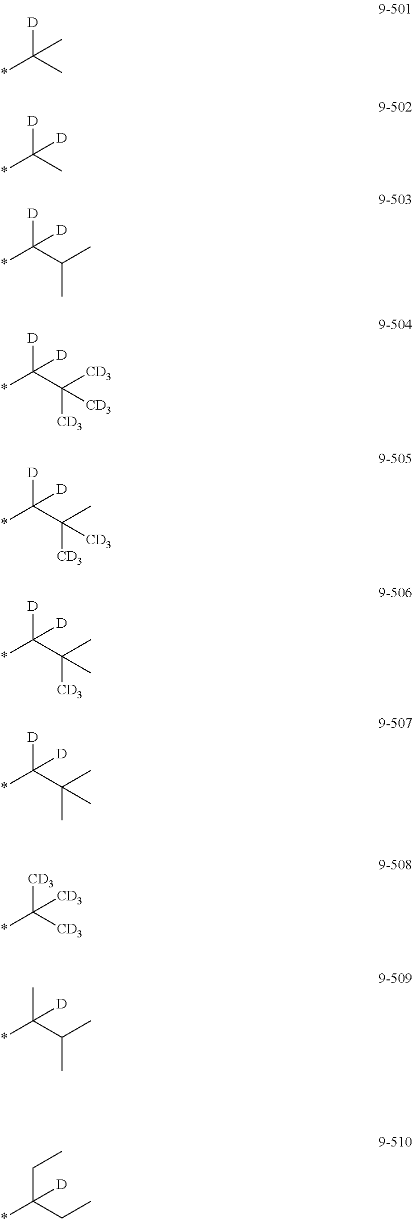

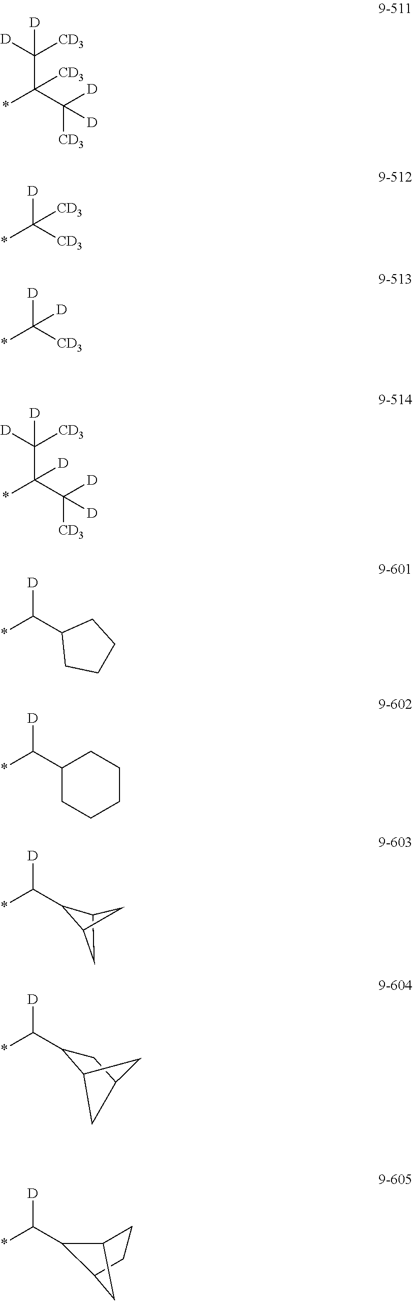

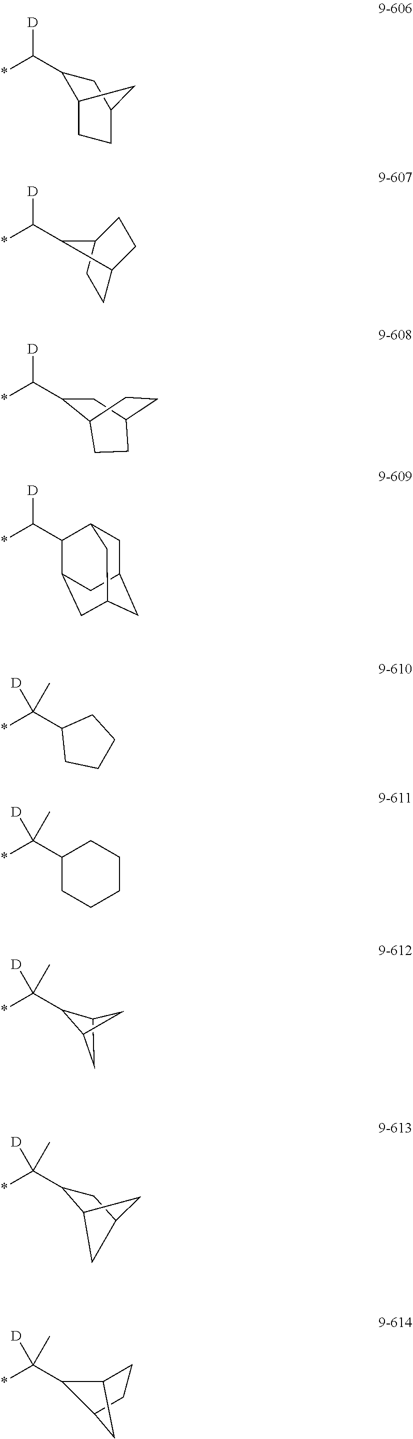

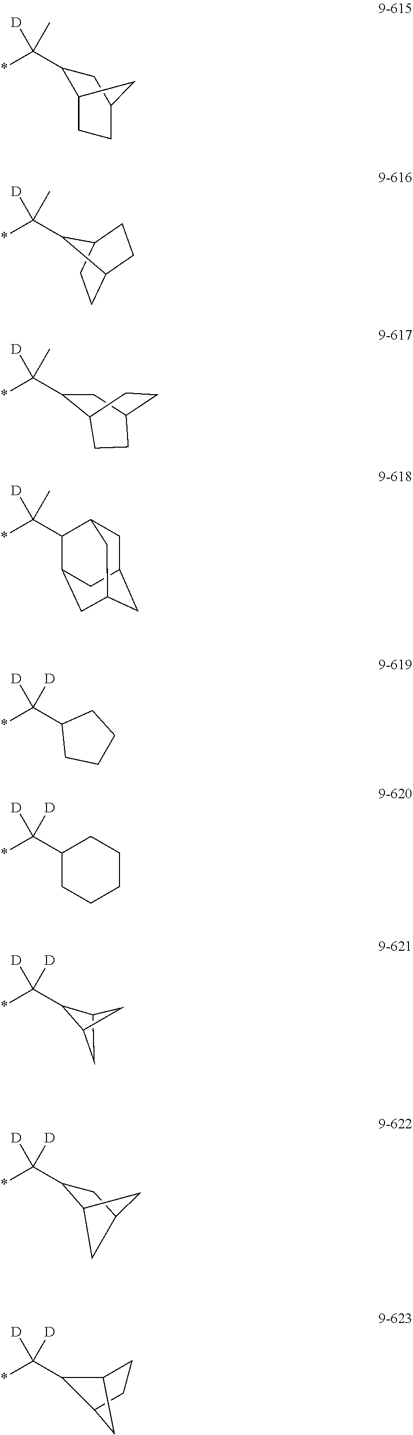

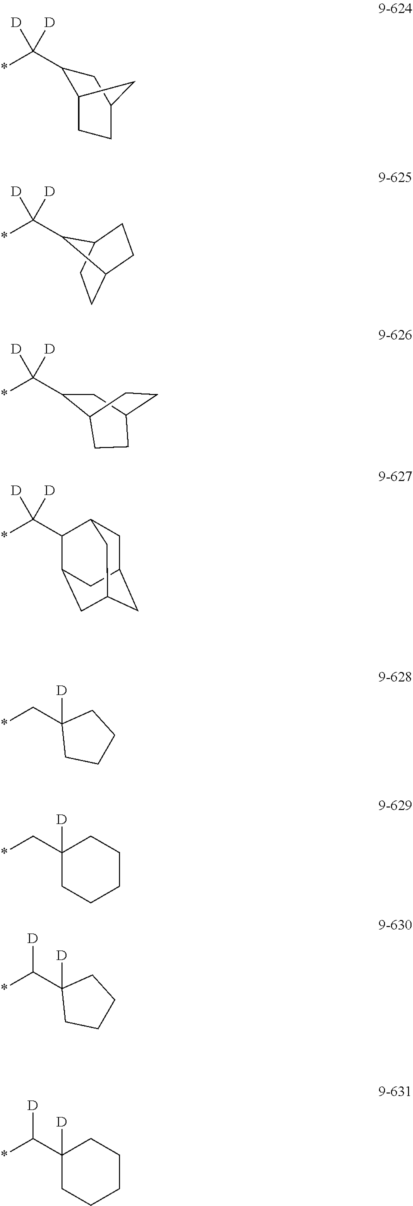

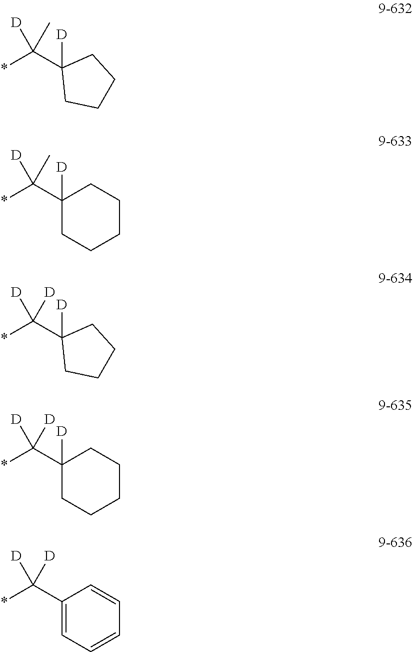

The “group represented by one of Formulae 9-1 to 9-39 in which at least one hydrogen is substituted with —F” and the “group represented by one of Formulae 9-201 to 9-237 in which at least one hydrogen is substituted with —F” may each be, for example, a group represented by one of Formulae 9-701 to 9-710:

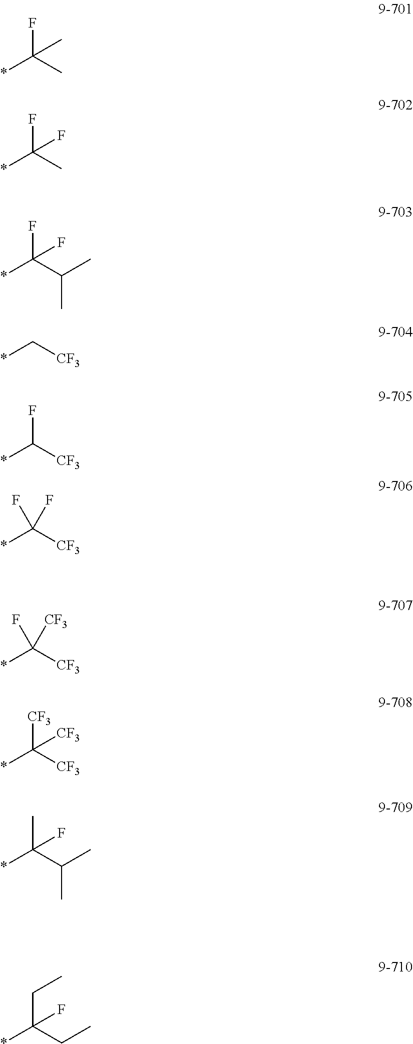

The “group represented by one of Formulae 10-1 to 10-129 in which at least one hydrogen is substituted with deuterium” and “the group represented by one of Formulae 10-201 to 10-350 in which at least one hydrogen is substituted with deuterium” may be, for example, a group represented by one of Formulae 10-501 to 10-553:

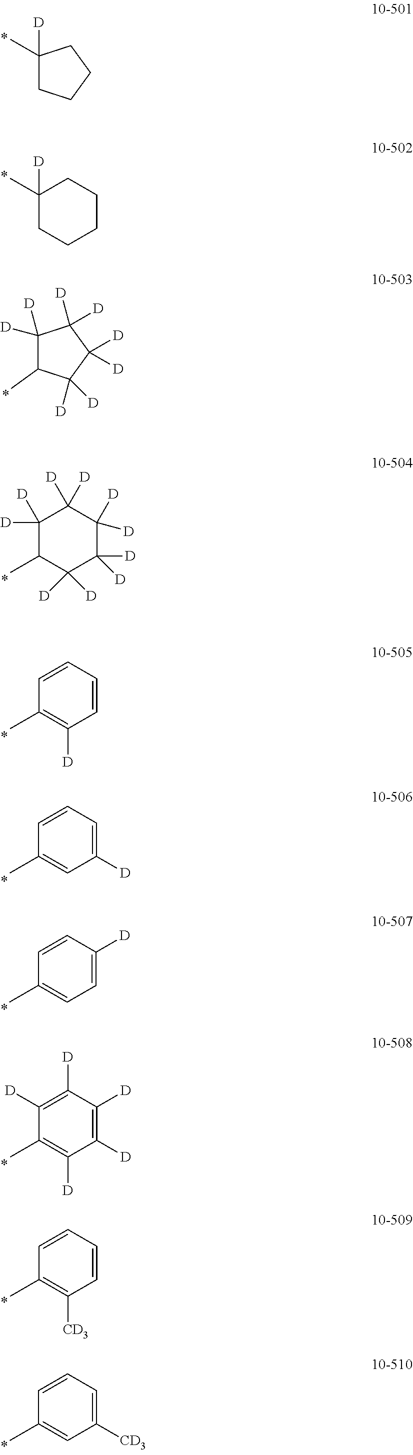

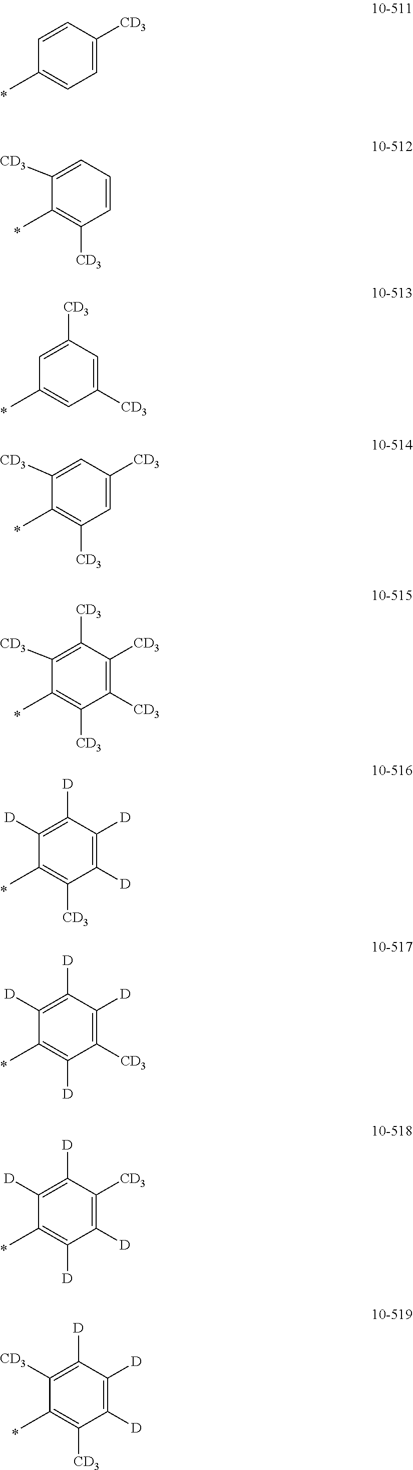

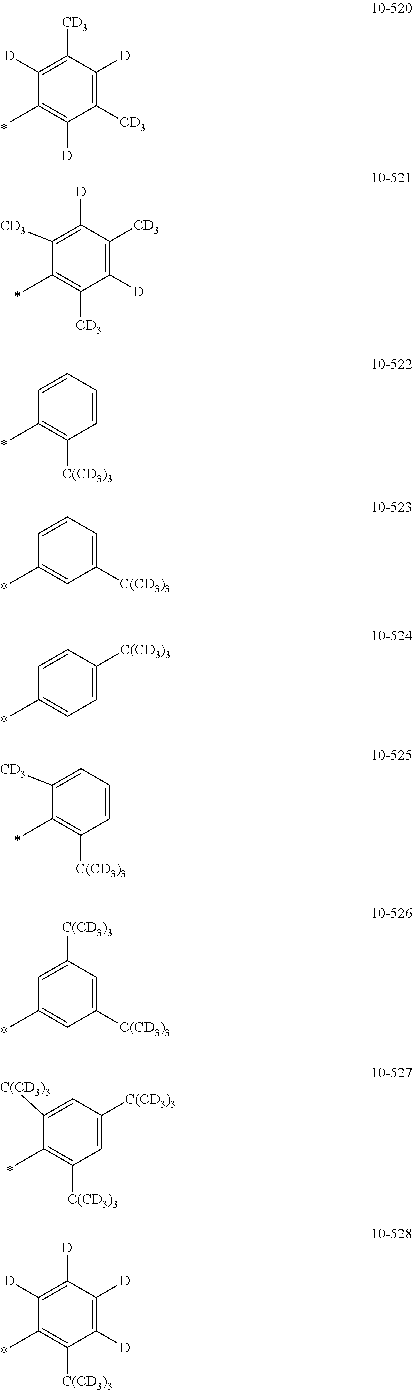

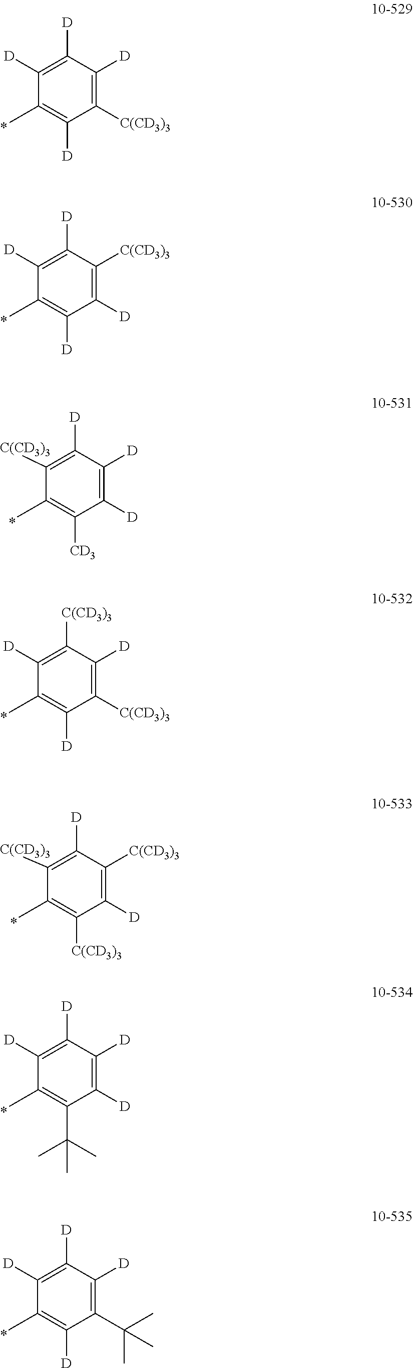

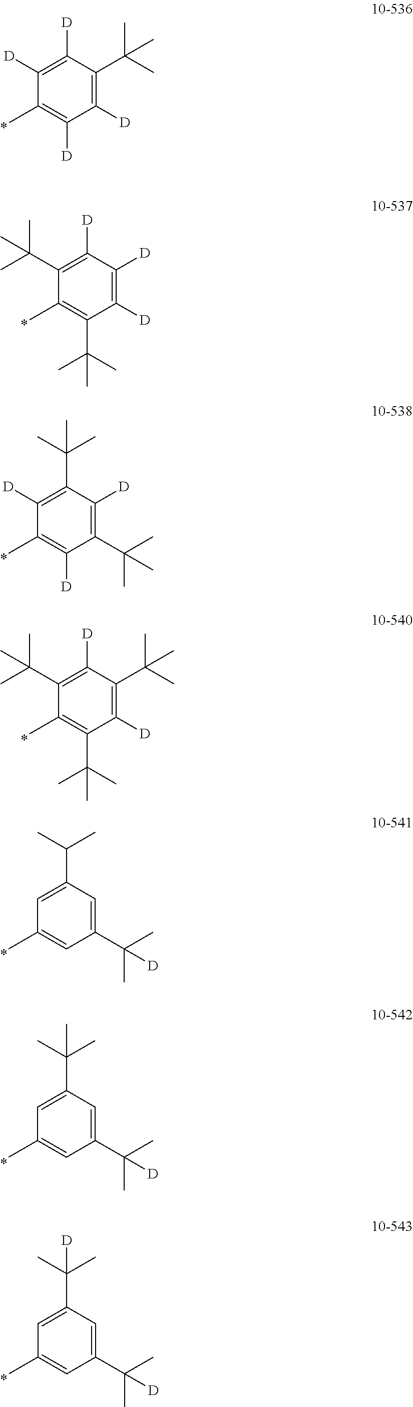

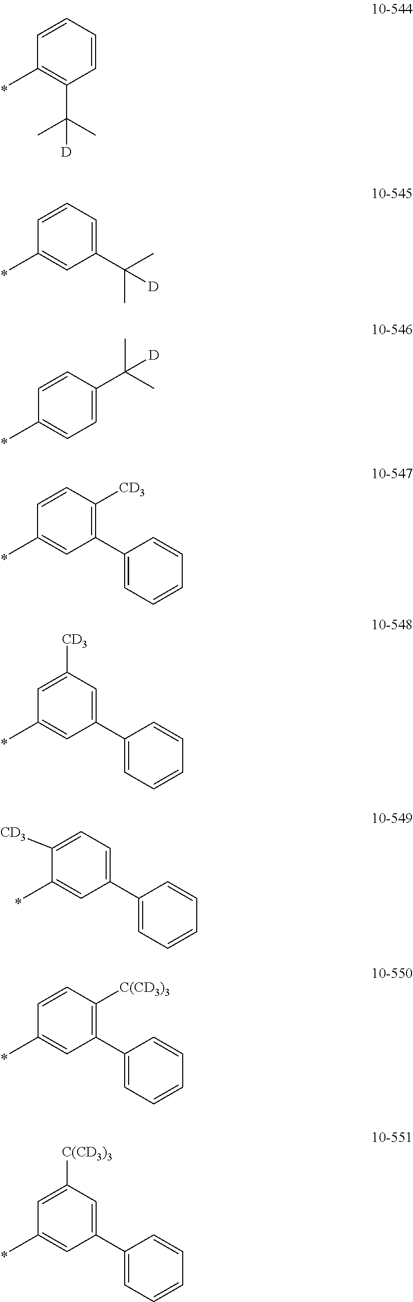

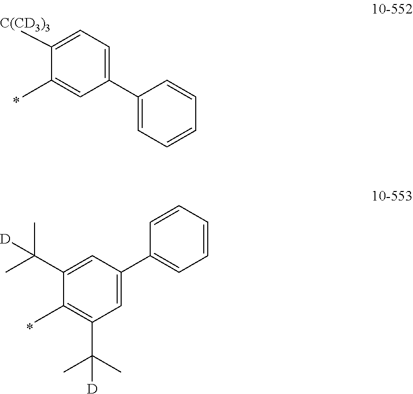

The “group represented by one of Formulae 10-1 to 10-129 in which at least one hydrogen is substituted with —F” and “the group represented by one of Formulae 10-201 to 10-350 in which at least one hydrogen is substituted with —F” may be, for example, a group represented by one of Formulae 10-601 to 10-617:

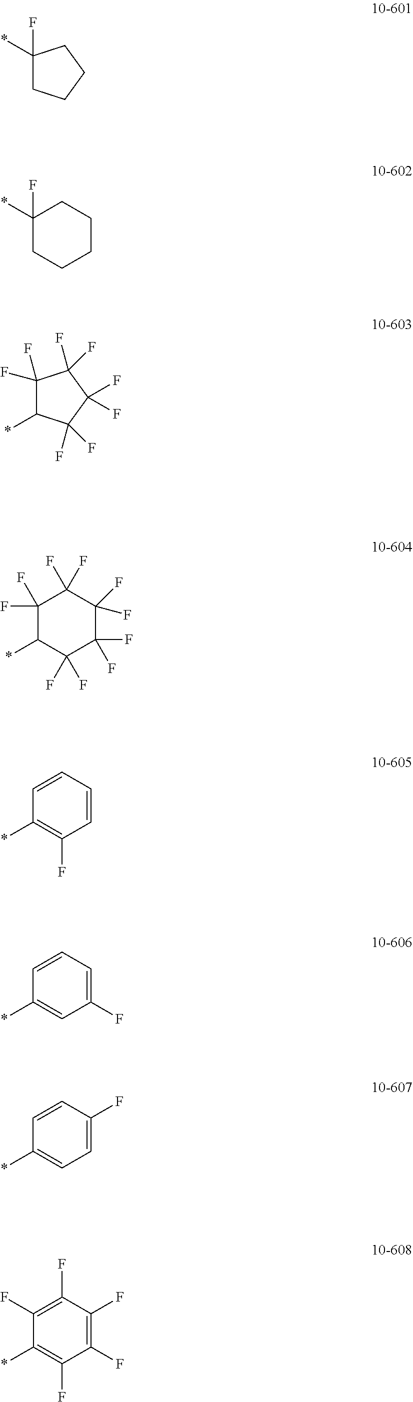

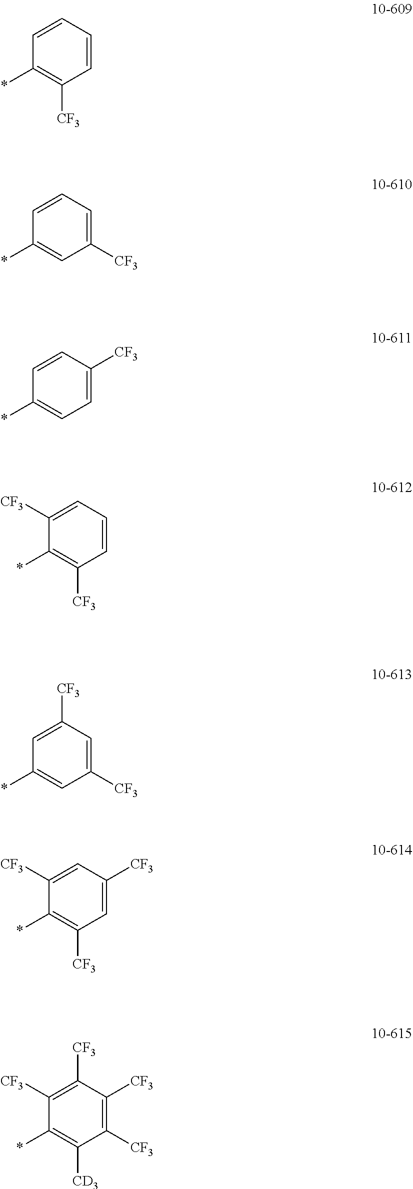

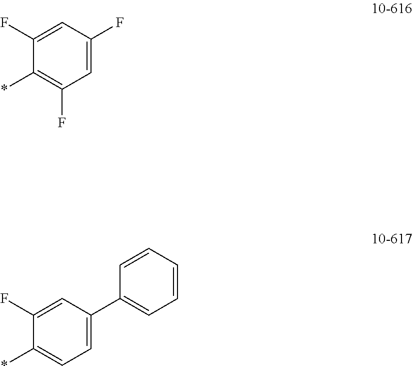 [SMILES: *c1c(F)cc(F)cc1F ; *c1ccc(-c2ccccc2)cc1F]

In Formulae 1, 2-1, and 2-2, c1 to c4 indicate the number of R₁(s) to the number of R₄(s), respectively; a1 to a4 indicate the number of a group(s) represented by *-[(L₁)_{b1}-(R₁)_{c1}], the number of a group(s) represented by *-[(L₂)_{b2}-(R₂)_{c2}], the number of a group(s) represented by *-[(L₃)_{b3}-(R₃)_{c3}], and the number of a group(s) represented by *-[(L₄)_{b4}-(R₄)_{c4}], respectively; e1 to e4 indicate the number of Z₁(s) to the number of Z₄(s), respectively; and d1 to d4 indicate the number of a group(s) represented by *—[W₁—(Z₁)ₑ₁], the number of a group(s) represented by *—[W₂—(Z₂)ₑ₂], the number of a group(s) represented by *—[W₃—(Z₃)ₑ₃], and the number of a group(s) represented by *—[W₄—(Z₄)ₑ₄], respectively, and may each independently be an integer from 0 to 20. When c1 is 2 or more, two or more of R₁(s) may be identical to or different from each other, when c2 is 2 or more, two or more of R₂(s) may be identical to or different from each other, when c3 is 2 or more, two or more of R₃(s) may be identical to or different from each other, when c4 is 2 or more, two or more of R₄(s) may be identical to or different from each other, when a1 is 2 or more, two or more of groups represented by *-[(L₁)_{b1}-(R₁)_{c1}] may be identical to or different from each other, when a2 is 2 or more, two or more of groups represented by *-[(L₂)_{b2}-(R₂)_{c2}] may be identical to or different from each other, when a3 is 2 or more, two or more of groups represented by *-[(L₃)_{b3}-(R₃)_{c3}] may be identical to or different from each other, when a4 is 2 or more, two or more of groups represented by *-[(L₄)_{b4}-(R₁)_{c4}] may be identical to or different from each other, when e1 is 2 or more, two or more of Z₁(s) may be identical to or different from each other, when e2 is 2 or more, two or more of Z₂(s) may be identical to or different from each other, when e3 is 2 or more, two or more of Z₃(s) may be identical to or different from each other, when e4 is 2 or more, two or more of Z₄(s) may be identical to or different from each other, when d1 is 2 or more, two or more of groups represented by *—[W₁—(Z₁)ₑ₁] may be identical to or different from each other, when d2 is 2 or more, two or more of groups represented by*—[W₂—(Z₂)ₑ₂] may be identical to or different from each other, when d3 is 2 or more, two or more of groups represented by *—[W₃—(Z₃)ₑ₃] may be identical to or different from each other, and when d4 is 2 or more, two or more of groups represented by *—[W₄—(Z₄)ₑ₁] may be identical to or different from each other. For example, in Formulae 1, 2-1, and 2-2, c1 to c4, a1 to a4, e1 to e4, and d1 to d4 may each independently be 0, 1, 2, or 3.

In one or more embodiments, the second compound may not be tris[2-phenylpyridine]iridium.

In one or more embodiments, in Formula 2-1, a case where Y₁ is N, ring A₁ is a pyridine group, Y₂ is C, ring A₂ is a benzene group, and each of d1 and d2 is 0 may be excluded.

In Formulae 1, 2-1, and 2-2, two or more substituents in at least one case of i) two or more of a plurality of R₁(s), ii) two or more of a plurality of R₂(s), iii) two or more of a plurality of R₃(s), iv) two or more of a plurality of R₄(s), v) R₅ₐ and R_{5b}, vi) two or more of a plurality of Z₁(s), vii) two or more of a plurality of Z₂(s), viii) two or more of a plurality of Z₃(s), ix) two or more of a plurality of Z₄(s), x) two or more of R₁ to R₄, R₅ₐ, and R_{5b}, and xi) two or more of Z₁ to Z₄ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ.

R₁₀ₐ may be as described in connection with R₁.

The signs * and *′ as used herein each indicate a binding site to a neighboring atom, unless otherwise stated.

In one or more embodiments, in Formula 1, n1 may not be 0, n4 may be 0, and a group represented by

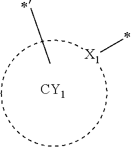

may be a group represented by one of Formulae CY1(1) to CY1(23):

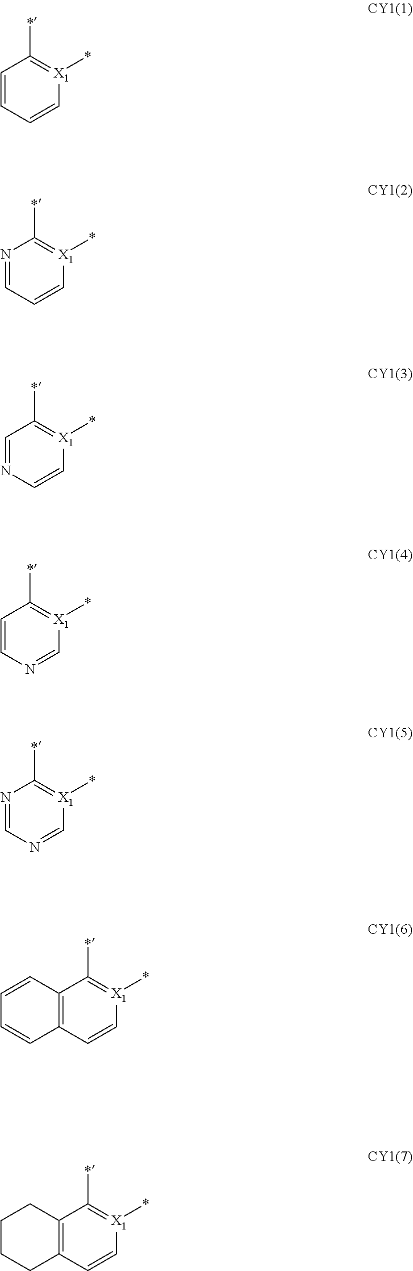

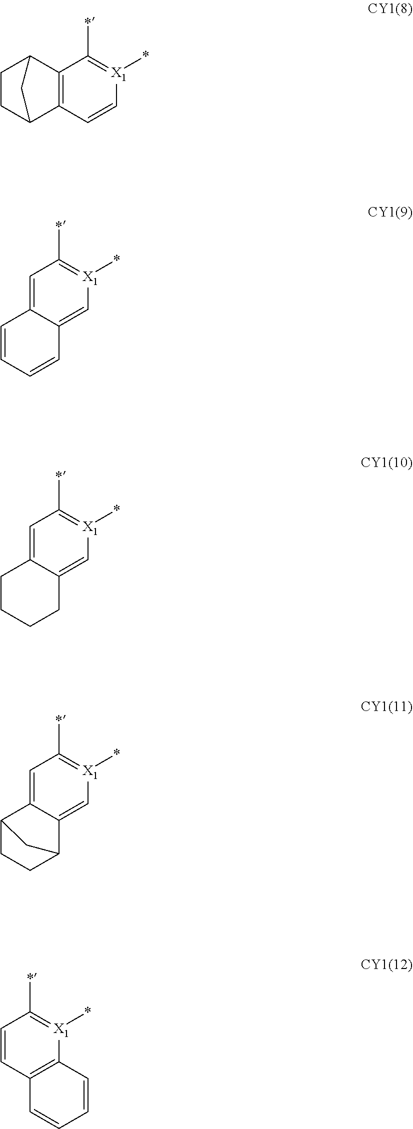

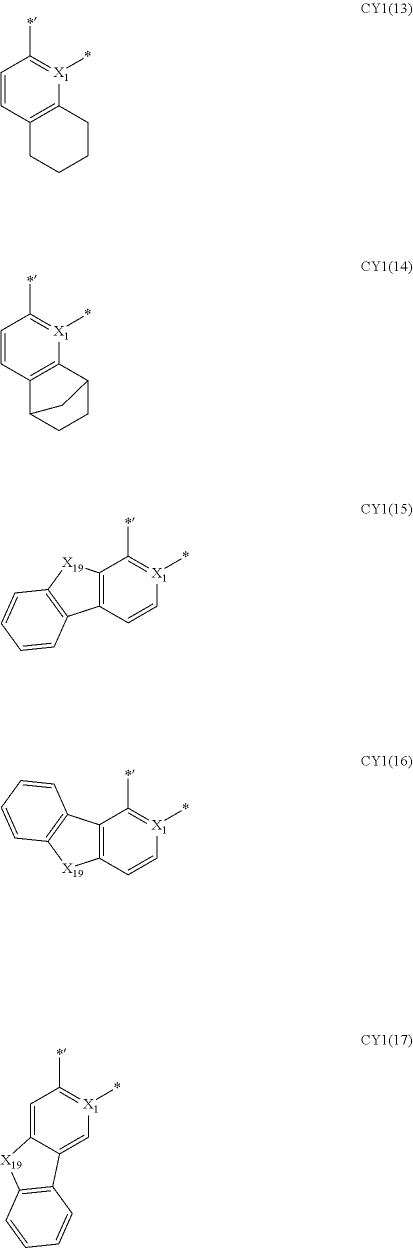

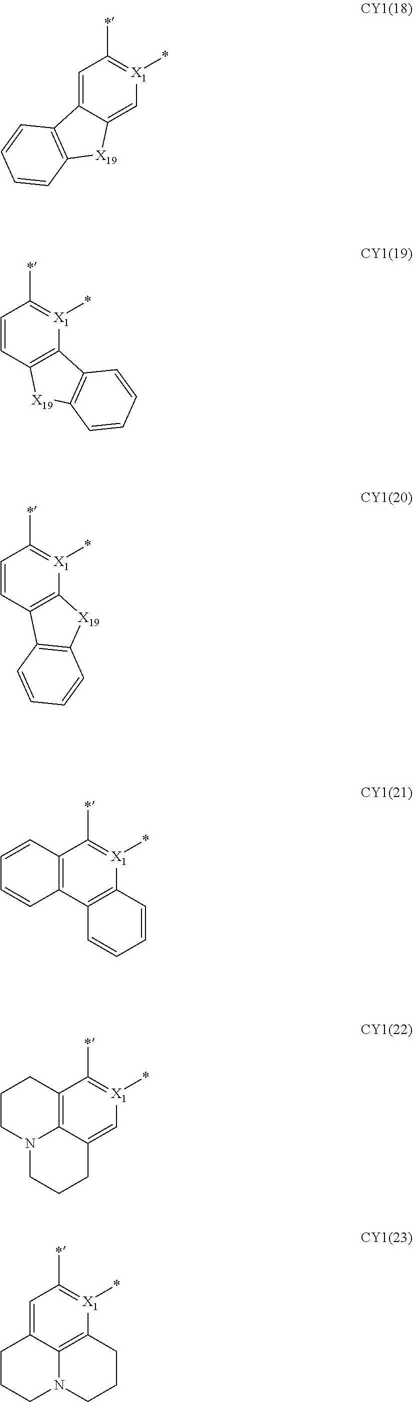

wherein, in Formulae CY1(1) to CY1(23),

X₁ may be as described herein,

X₁₉ may be O, S, Se, N(R₁₉ₐ), C(R₁₉ₐ)(R_{19b}), or Si(R₁₉ₐ)(R_{19b}),

R₁₉ₐ and R_{19b} may each be as described in connection with R₁,

* indicates a binding site to X₅ or M₁ in Formula 1, and

*′ indicates a binding site to T₁₁ in Formula 1.

In one or more embodiments, in Formula 1, n1 may be 1, n4 may be 0, and a group represented by

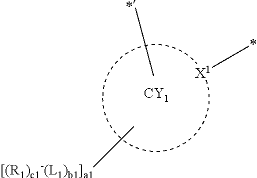

may be a group represented by one of Formulae CY1-1 to CY1-18:

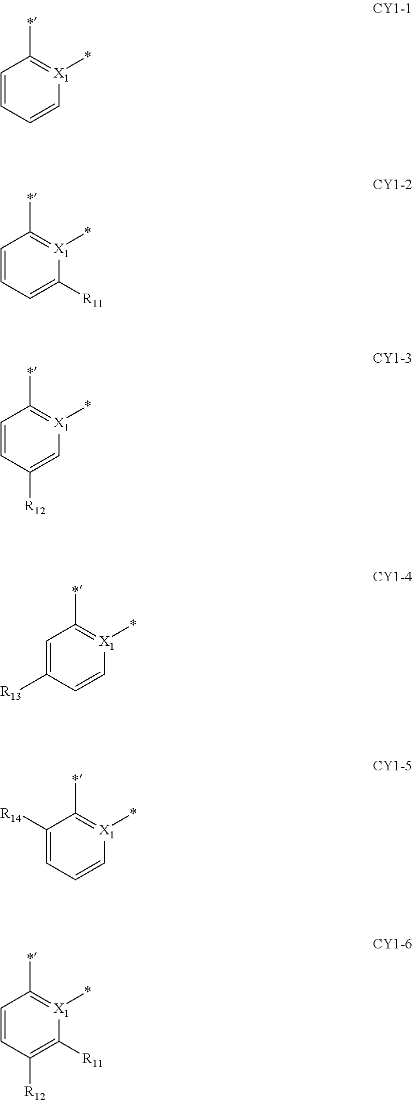

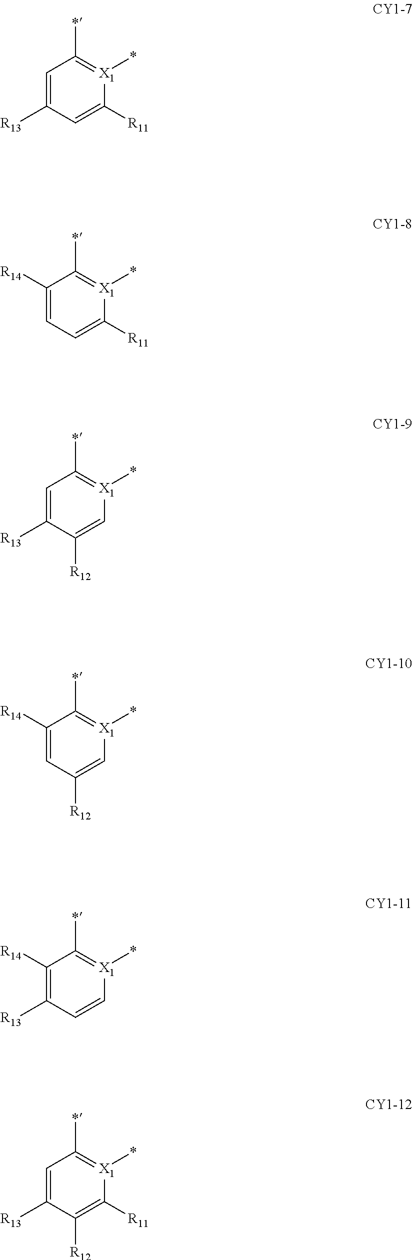

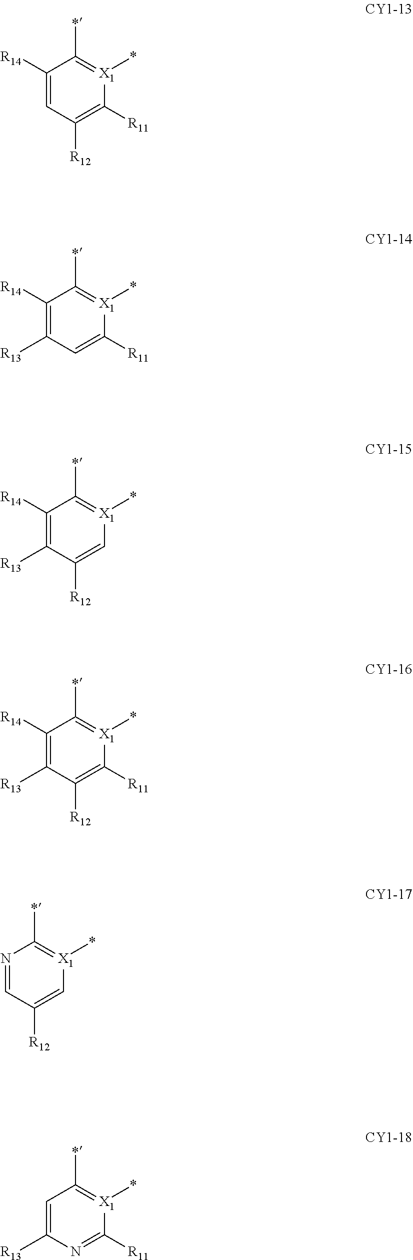

wherein, in Formulae CY1-1 to CY1-18,

X₁ may be as described herein,

R₁₁ to R₁₄ may each be as described in connection with R₁, and each of R₁₁ to R₁₄ may not be hydrogen,

* indicates a binding site to X₅ or Mu in Formula 1, and

*′ indicates a binding site to T₁₁ in Formula 1.

In one or more embodiments, in Formula 1, n1 and n2 may each be 1, and ring CY₂ may be a group represented by Formula CY2A or CY2B:

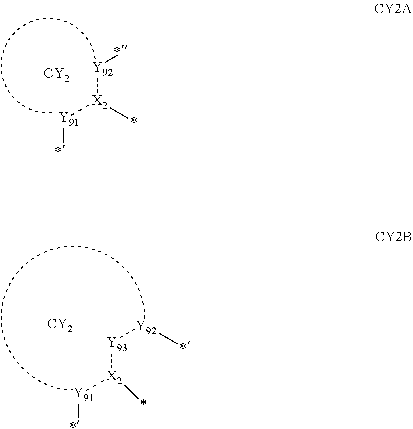

wherein, in Formulae CY2A and CY2B,

X₂ and CY₂ may each be as described herein,

Y₉₁ to Y₉₃ may each independently be O, S, N, C, or Si,

in Formulae CY2A and CY2B, a bond between X₂ and Y₉₁, a bond between X₂ and Y₉₂, a bond between X₂ and Y₉₃, and a bond between Y₂₂ and Y₉₃ may each be a chemical bond,

*′ indicates a binding site to T₁₁ in Formula 1,

* indicates a binding site to X₆ or M₁ in Formula 1, and

*″ indicates a binding site to T₁₂ in Formula 1.

In one or more embodiments, in Formula 1, each of n1 and n2 may not be 0, and a group represented by

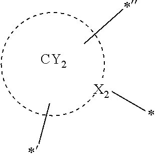

may be a group represented by one of Formulae CY2(1) to CY2(21):

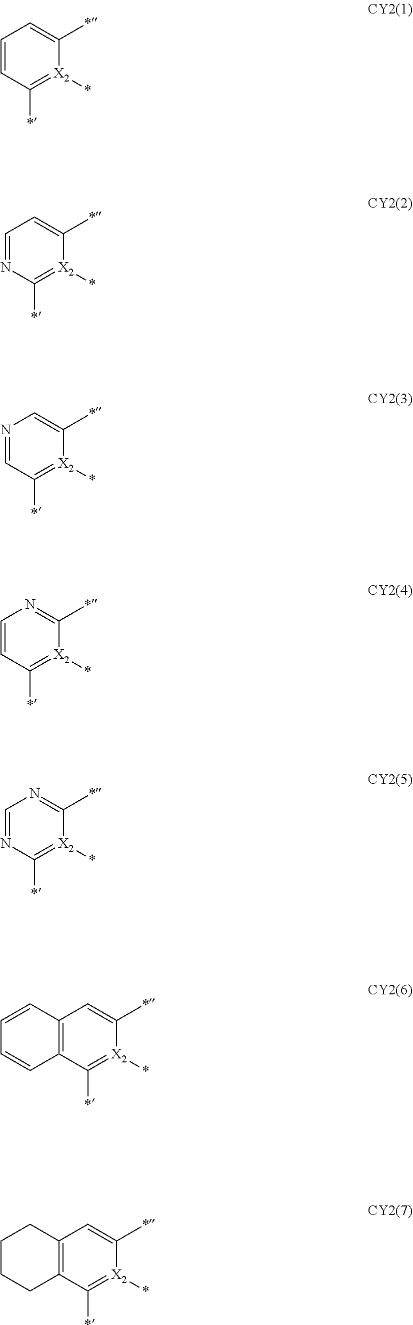

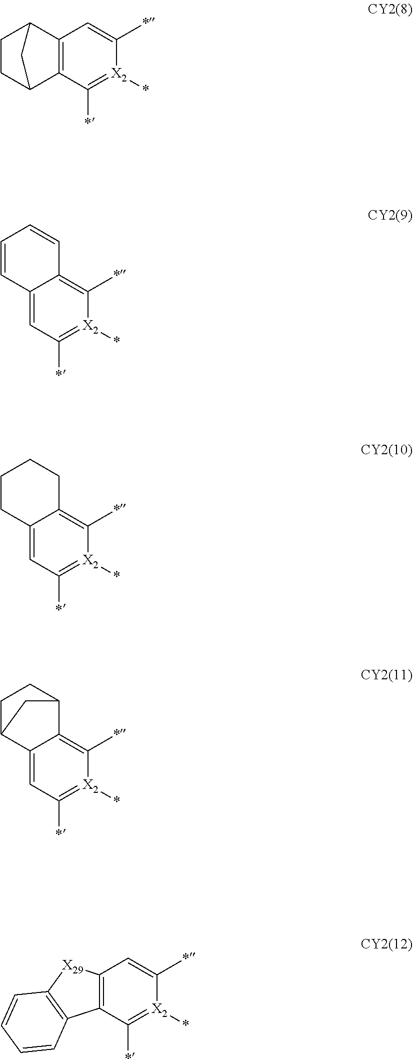

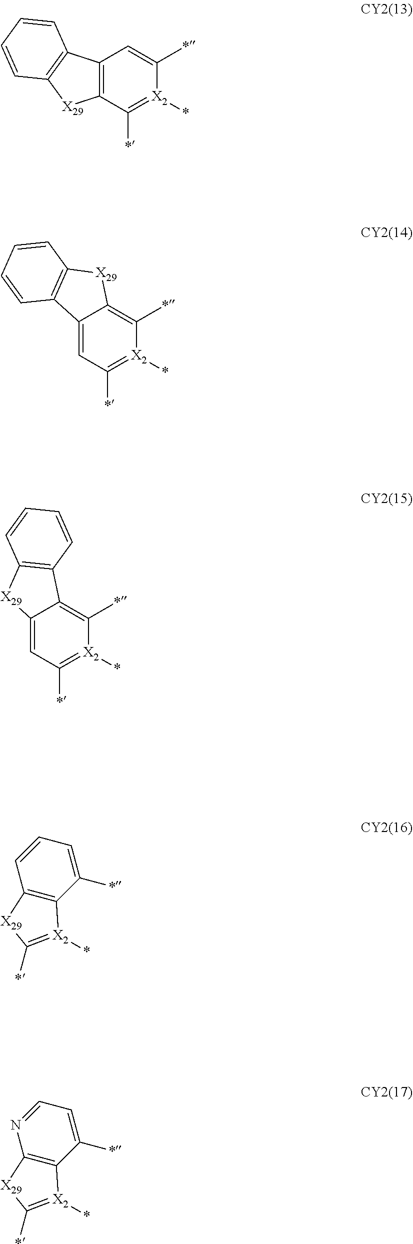

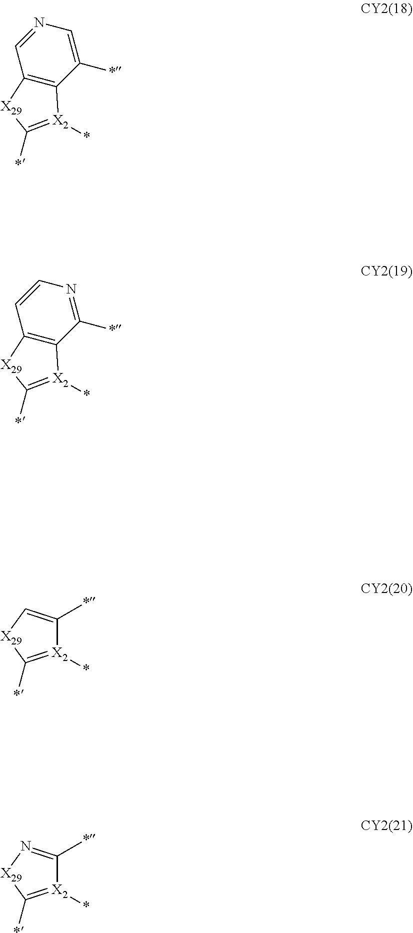

wherein, in Formulae CY2(1) to CY2(21),

X₂ may be as described herein,

X₂₉ may be O, S, N-[(L₂)_{b2}-(R₂)_{c2}], C(R₂₉ₐ)(R_{29b}), or Si(R₂₉ₐ)(R_{29b}),

L₂, b2, R₂, and c2 may each be as described herein,

R₂₉ₐ and R_{29b} may each be as described in connection with R₂,

*′ indicates a binding site to T₁₁ in Formula 1,

* indicates a binding site to X₆ or M₁ in Formula 1, and

*″ indicates a binding site to T₁₂ in Formula 1.

In one or more embodiments, in Formula 1, each of n1 and n2 may be 1, and a group represented by

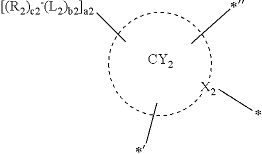

may be a group represented by one of Formulae CY2-1 to CY2-16:

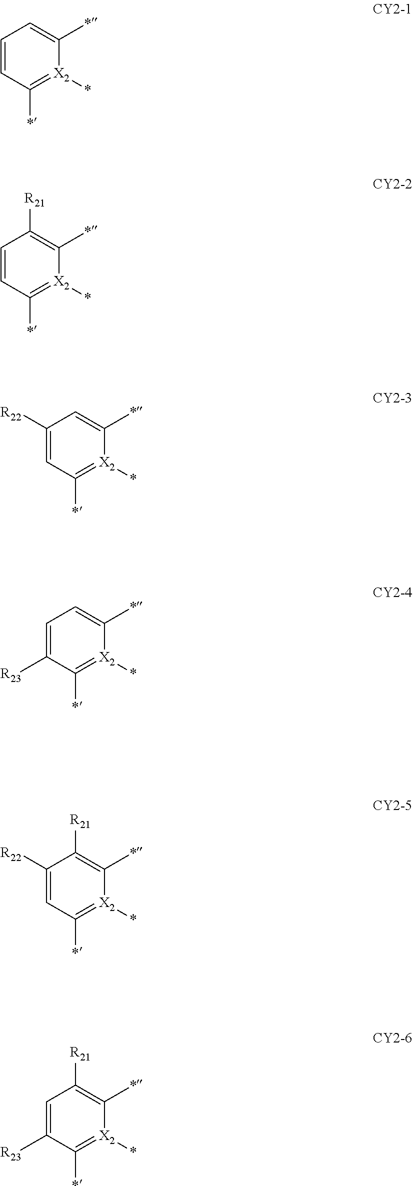

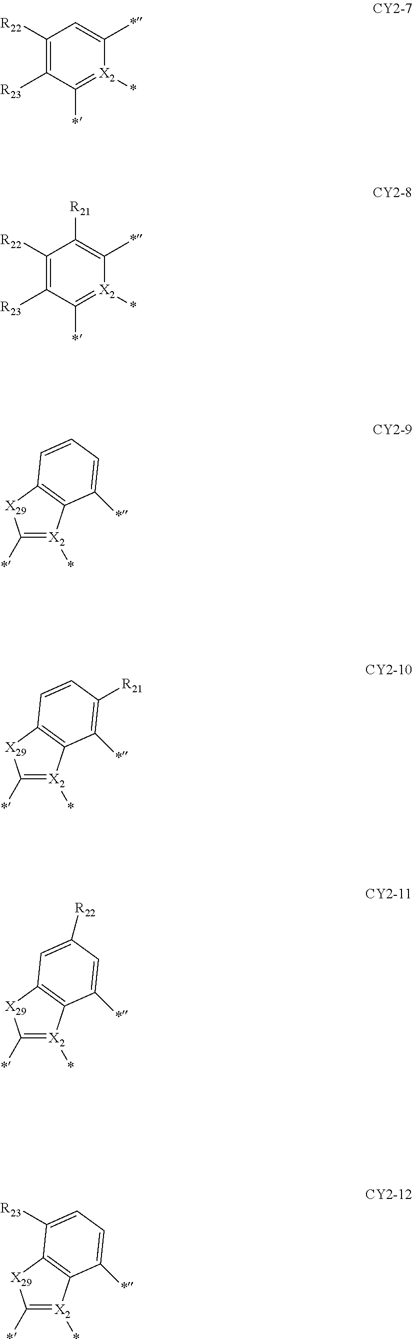

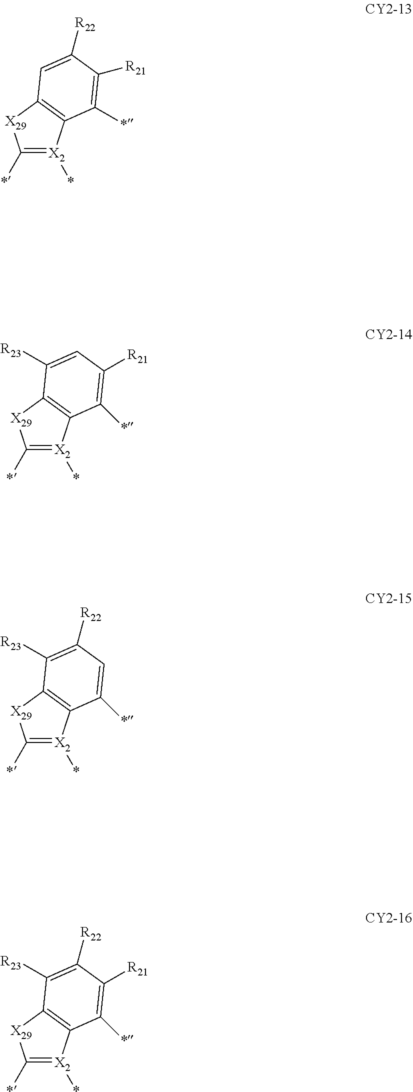

wherein, in Formulae CY2-1 to CY2-16,

X₂ may be as described herein,

X₂₉ may be O, S, N-[(L₂)_{b2}-(R₂)_{c2}], C(R₂₉ₐ)(R_{29b}), or Si(R₂₉ₐ)(R_{29b}),

L₂, b2, R₂, and c2 may each be as described herein,

R₂₁ to R₂₃, R₂₉ₐ, and R_{29b} may each be as described in connection with R₂, wherein each of R₂₁ to R₂₃ may not be hydrogen,

*′ indicates a binding site to T₁₁ in Formula 1,

* indicates a binding site to X₆ or M₁ in Formula 1, and

*″ indicates a binding site to T₁₂ in Formula 1.

In one or more embodiments, in Formula 1,

each of n1 and n2 may be 1,

a group represented by

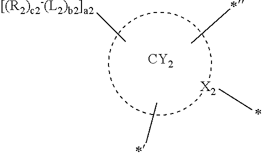

may be represented by one of Formulae CY2-9 to CY2-16,

X₂₉ in Formulae CY2-9 to CY2-16 may be N-[(L₂)_{b2}-(R₂)_{c2}],

L₂ may be a benzene group unsubstituted or substituted with at least one R₁₀ₐ,

b2 may be 1 or 2,

c2 may be 1 or 2,

when c2 is 1, R₂ may be a phenyl group unsubstituted or substituted with at least one of deuterium, a C₁-C₂₀ alkyl group, a phenyl group, a deuterated phenyl group, a (C₁-C₂₀alkyl)phenyl group, or a combination thereof; and when c2 is 2, a) one of two R₂(s) may be a phenyl group unsubstituted or substituted with at least one of deuterium, a C₁-C₂₀ alkyl group, a phenyl group, a deuterated phenyl group, a (C₁-C₂₀alkyl)phenyl group, or a combination thereof, b) and the other R₂ may be a C₄-C₂₀ alkyl group unsubstituted or substituted with at least one C₃-C₁₀ cycloalkyl group, or a deuterated C₁-C₂₀ alkyl group.

In one or more embodiments, in Formula 1, each of n2 and n3 may not be 0, and a group represented by

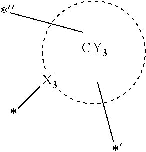

may be a group represented by one of Formulae CY3(1) to CY3(15):

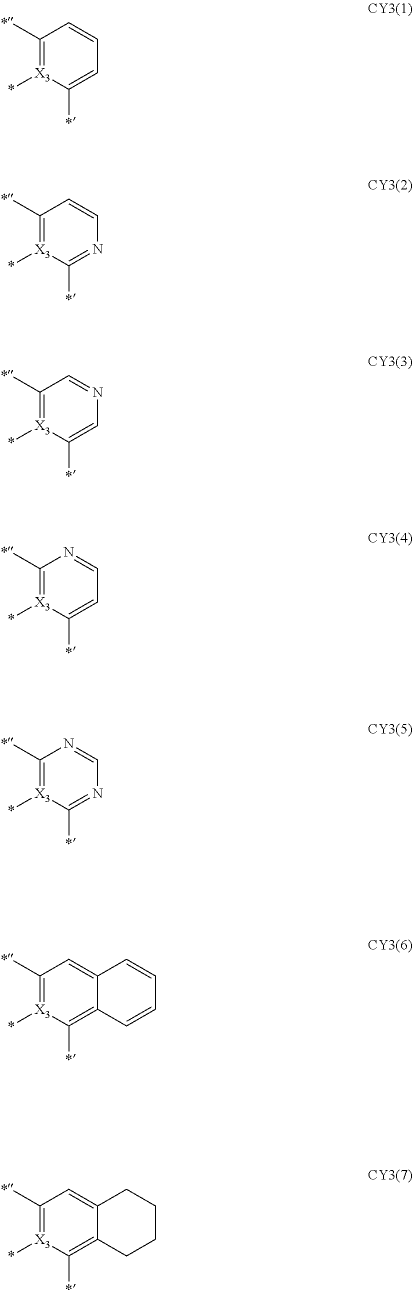

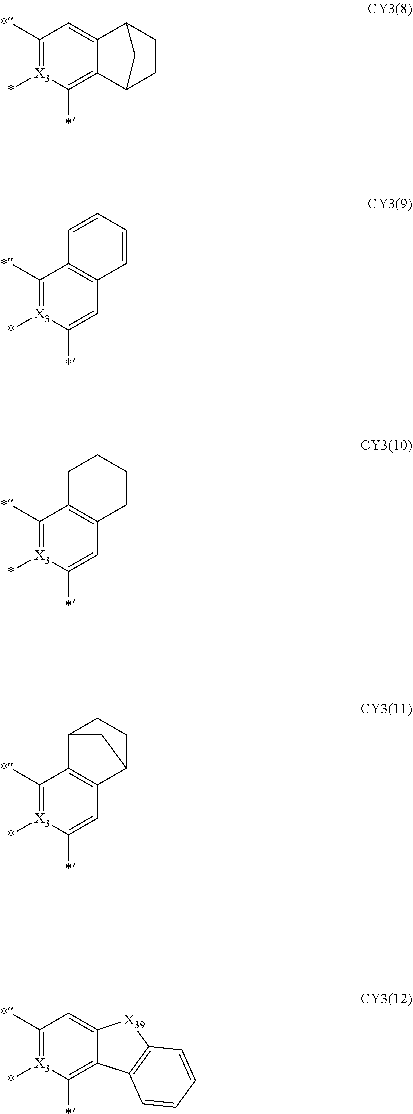

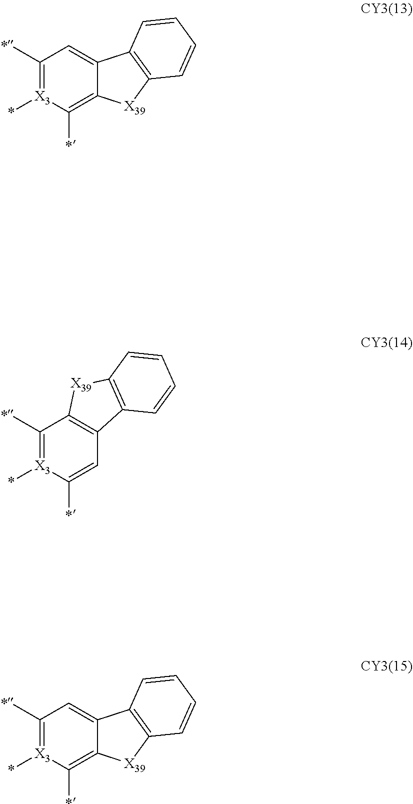

wherein, in Formulae CY3(1) to CY3(15),

X₃ may be as described herein,

X₃₉ may be O, S, N(Z₃₉ₐ), C(R₃₉ₐ)(R_{39b}), or Si(R₃₉ₐ)(R_{39b}),

R₃₉ₐ and R_{39b} may each be as described in connection with R₃,

*″ indicates a binding site to T₁₂ in Formula 1,

* indicates a binding site to X₇ or M₁ in Formula 1, and

*′ indicates a binding site to T₁₃ in Formula 1.

In one or more embodiments, in Formula 1, each of n2 and n3 may be 1, and a group represented by

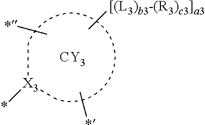

may be a group represented by one of Formulae CY3-1 to CY3-13:

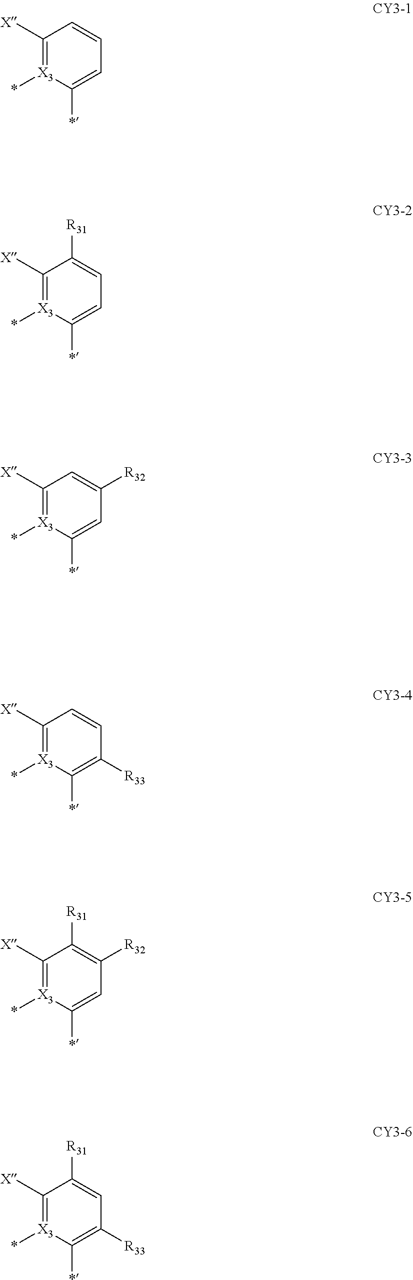

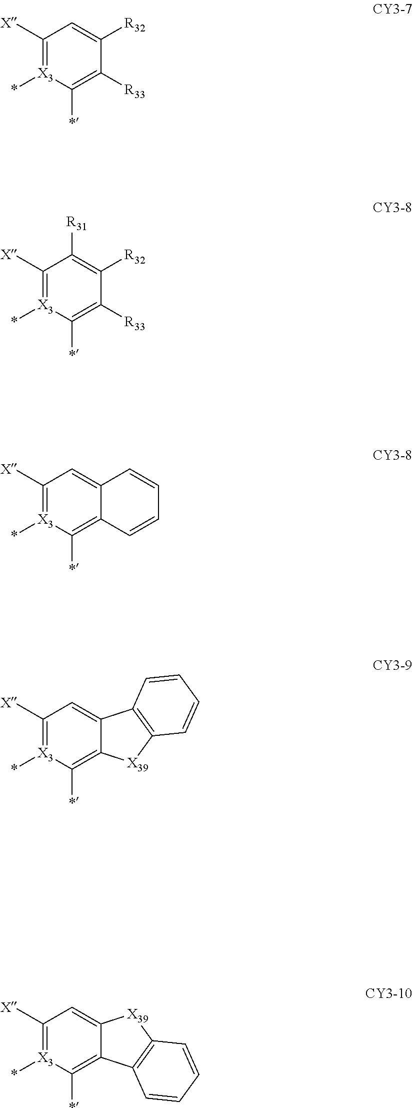

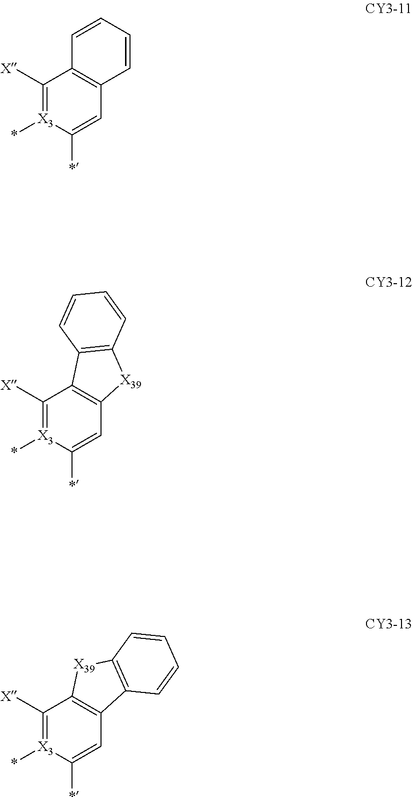

wherein, in Formulae CY3-1 to CY3-13,

X₃ may be as described herein,

X₃₉ may be O, S, N-[(L₃)_{b3}-(R₃)_{c3}], C(R₃₉ₐ)(R_{39b}), or Si(R₃₉ₐ)(R_{39b}),

L₃, b3, R₃, and c3 may each be as described herein,

R₃₁ to R₃₃, R₃₉ₐ, and R_{39b} may each be as described in connection with R₃, wherein each of R₃₁ to R₃₃ may not be hydrogen,

*″ indicates a binding site to T₁₂ in Formula 1,

* indicates a binding site to X₇ or M₁ in Formula 1, and

*′ indicates a binding site to T₁₃ in Formula 1.

In one or more embodiments, in Formula 1, n3 may not be 0, n4 may be 0, and a group represented by

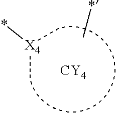

may be a group represented by one of Formulae CY4(1) to CY4(20):

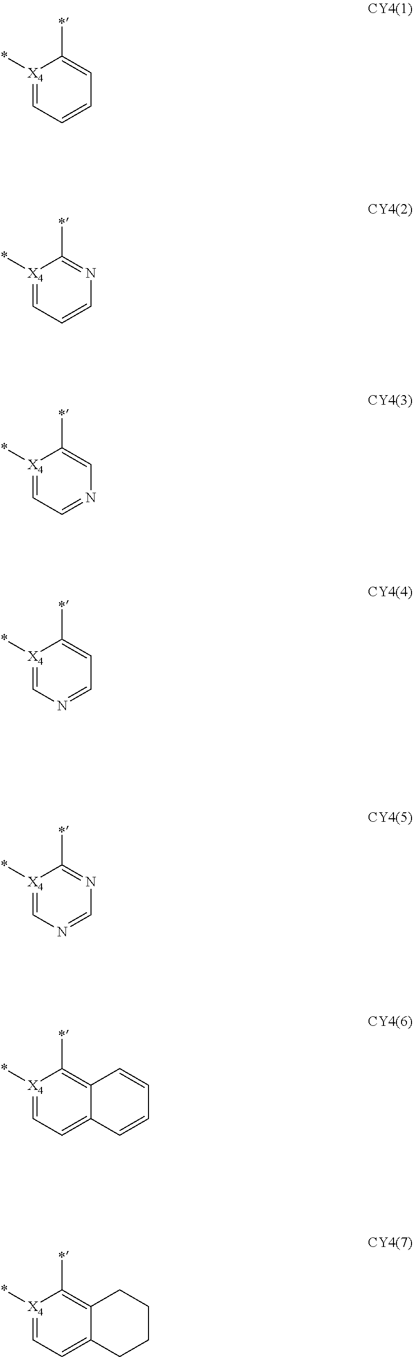

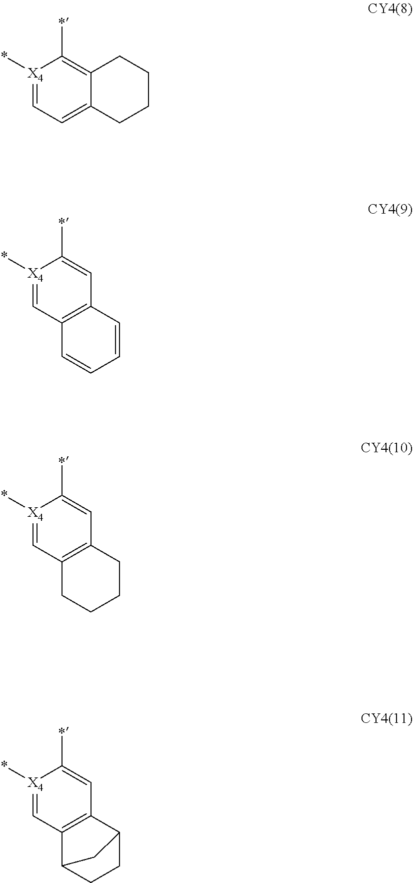

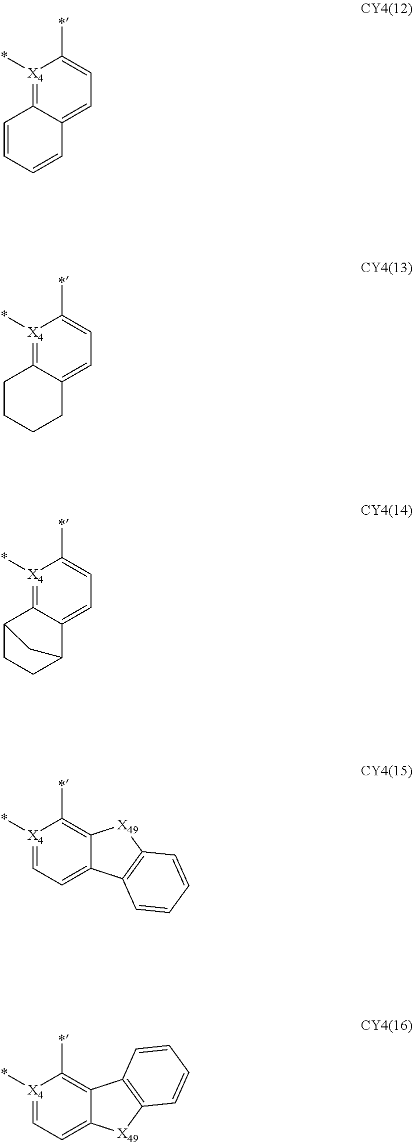

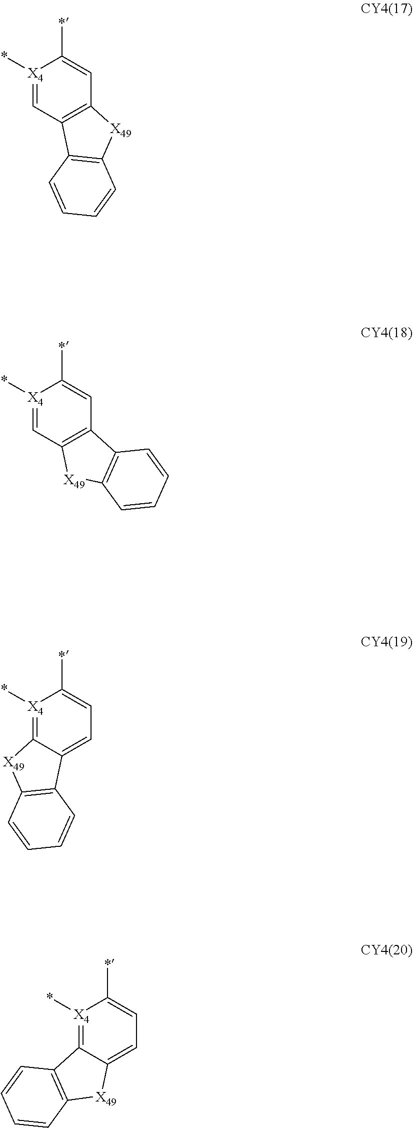

wherein, in Formulae CY4(1) to CY4(20),

X₄ may be as described herein,

X₄₉ may be O, S, N(R₄₉ₐ), C(R₄₉ₐ)(R_{49b}), or Si(R₄₉ₐ)(R_{49b}),

R₄₉ₐ and R_{49b} may each be as described in connection with R₄,

*′ indicates a binding site to T₁₃ in Formula 1, and

* indicates a binding site to X₈ or M₁ in Formula 1.

In one or more embodiments, in Formula 1, n3 may be 1, n4 may be 0, and a group represented by

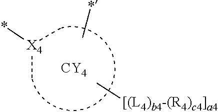

may be a group represented by one of Formulae CY4-1 to CY4-16:

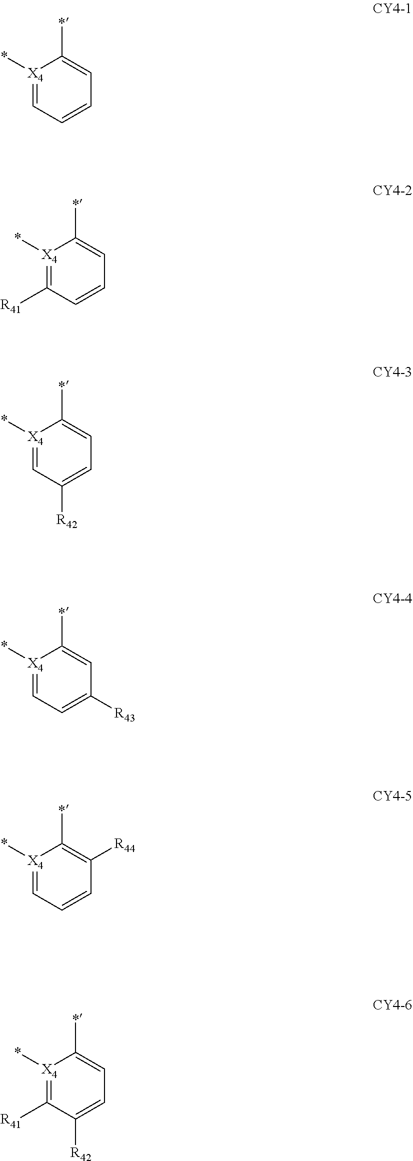

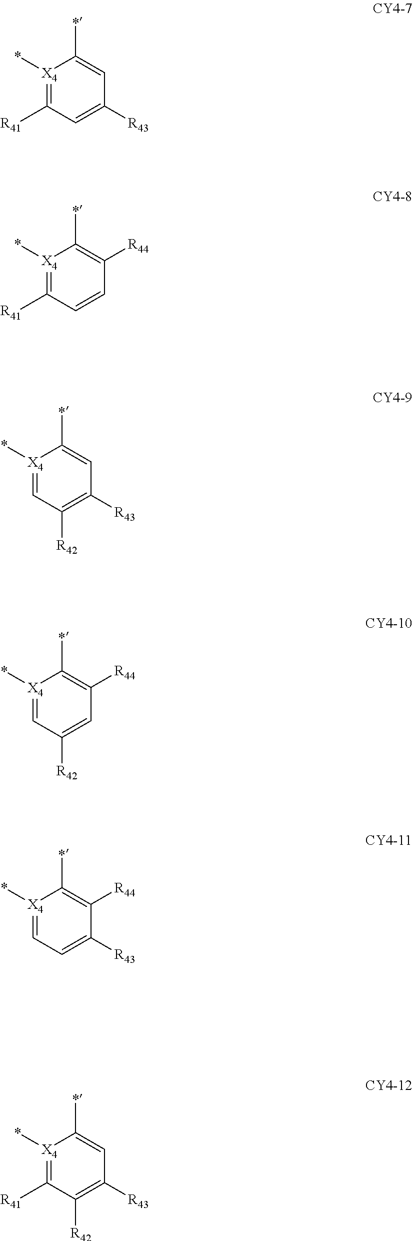

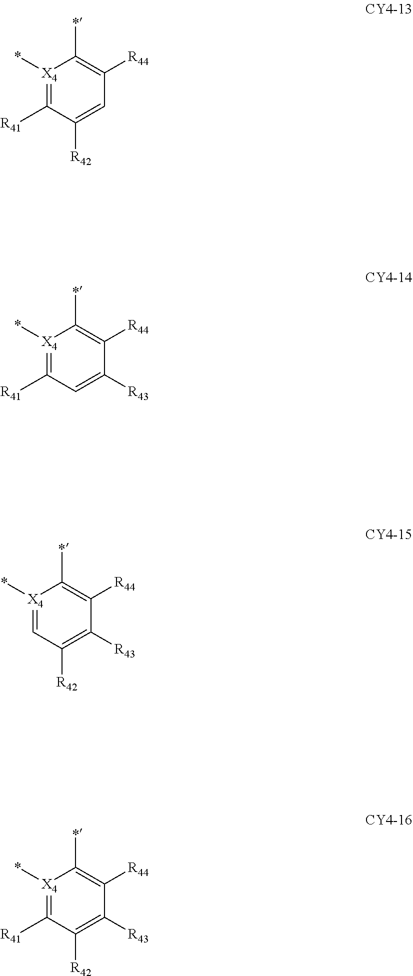

wherein, in Formulae CY4-1 to CY4-16,

X₄ may be as described herein,

R₄₁ to R₄₄ may each be as described in connection with R₄, and each of R₄₁ to R₄₄ may not be hydrogen,

*′ indicates a binding site to T₁₃ in Formula 1, and

* indicates a binding site to X₈ or M₁ in Formula 1.

In one or more embodiments, the first compound may be a compound represented by one of Formulae 1-1 to 1-3:

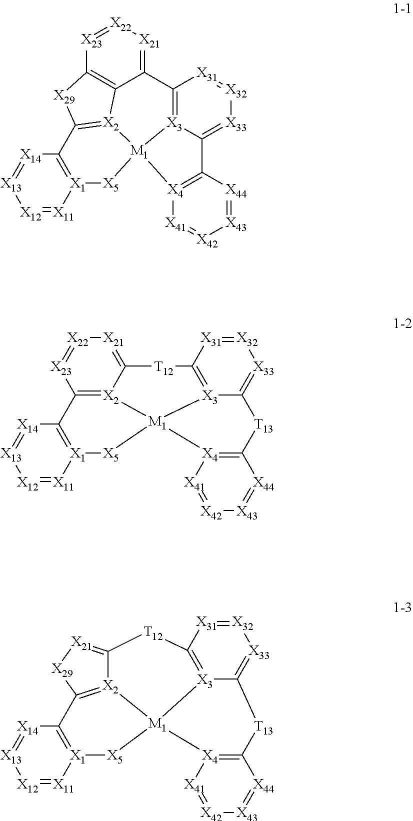

wherein, in Formulae 1-1 to 1-3,

M₁, X₁ to X₅, T₁₂, and T₁₃ may each be as described herein,

X₁₁ may be N or C(R₁₁), X₁₂ may be N or C(R₁₂), X₁₃ may be N or C(R₁₃), and X₁₄ may be N or C(R₁₄),

R₁₁ to R₁₄ may each be as described in connection with R₁,

two or more of R₁₁ to R₁₄ may optionally be linked to each other to form a C₅-C₃₀ carbocyclic group unsubstituted or substituted with at least one R₁₀ₐ or a C₁-C₃₀ heterocyclic group unsubstituted or substituted with at least one R₁₀ₐ,

X₂₁ may be N or C(R₂₁), X₂₂ may be N or C(R₂₂), and X₂₃ may be N or C(R₂₃),

X₂₉ may be O, S, N-[(L₂)_{b2}-(R₂)_{c2}], C(R₂₉ₐ)(R_{29b}), or Si(R₂₉ₐ)(R_{29b},

L₂, b2, R₂, and c2 may each be as described herein,

R₂₁ to R₂₃, R₂₉ₐ, and R_{29b} may each be as described in connection with R₂,

two or more of R₂₁ to R₂₃ may optionally be linked to each other to form a C₅-C₃₀ carbocyclic group unsubstituted or substituted with at least one R₁₀ₐ or a C₁-C₃₀ heterocyclic group unsubstituted or substituted with at least one R₁₀ₐ,

X₃₁ may be N or C(R₃₁), X₃₂ may be N or C(R₃₂), and X₃₃ may be N or C(R₃₃),

R₃₁ to R₃₃ may each be as described in connection with R₃,

two or more of R₃₁ to R₃₃ may optionally be linked to each other to form a C₅-C₃₀ carbocyclic group unsubstituted or substituted with at least one R₁₀ₐ or a C₁-C₃₀ heterocyclic group unsubstituted or substituted with at least one R₁₀ₐ,

X₄₁ may be N or C(R₄₁), X₄₂ may be N or C(R₄₂), X₄₃ may be N or C(R₄₃), and X₄₄ may be N or C(R₄₄),

R₄₁ to R₄₄ may each be as described in connection with R₄, and

two or more of R₄₁ to R₄₄ may optionally be linked to each other to form a C₅-C₃₀ carbocyclic group unsubstituted or substituted with at least one R₁₀ₐ, or a C₁-C₃₀ heterocyclic group unsubstituted or substituted with at least one R₁₀ₐ.

In one or more embodiments,

Y₁ in Formula 2-1 may be N, and

a group represented by

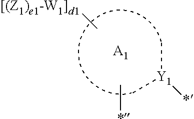

in Formula 2-1 may be a group represented by one of Formulae A1-1 to A1-3:

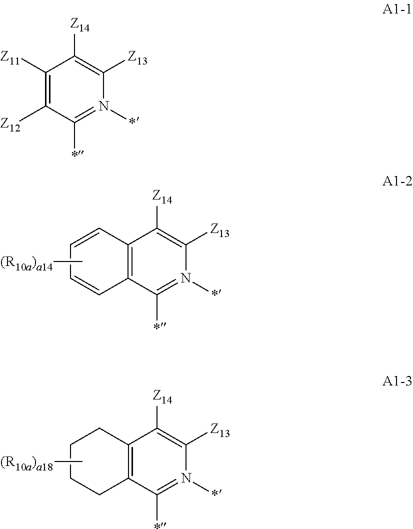

wherein, in Formulae A1-1 to A1-3,

Z₁₁ to Z₁₄ may each be as described in connection with

R₁₀ₐ may be as described in connection with R₁₀ₐ,

a14 may be an integer from 0 to 4,

a18 may be an integer from 0 to 8,

*′ indicates a binding site to M₂ in Formula 2, and

*″ indicates a binding site to ring A₂.

For example, in Formulae A1-1 to A1-3, Z₁₄ may be a deuterated C₁-C₂₀ alkyl group, —Si(Q₃)(Q₄)(Q₅), or —Ge(Q₃)(Q₄)(Q₅).

In one or more embodiments,

Y₃ in Formula 2-2 may be N, and

a group represented by

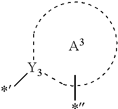

in Formula 2-2 may be a group represented by one of Formulae NR1 to NR48:

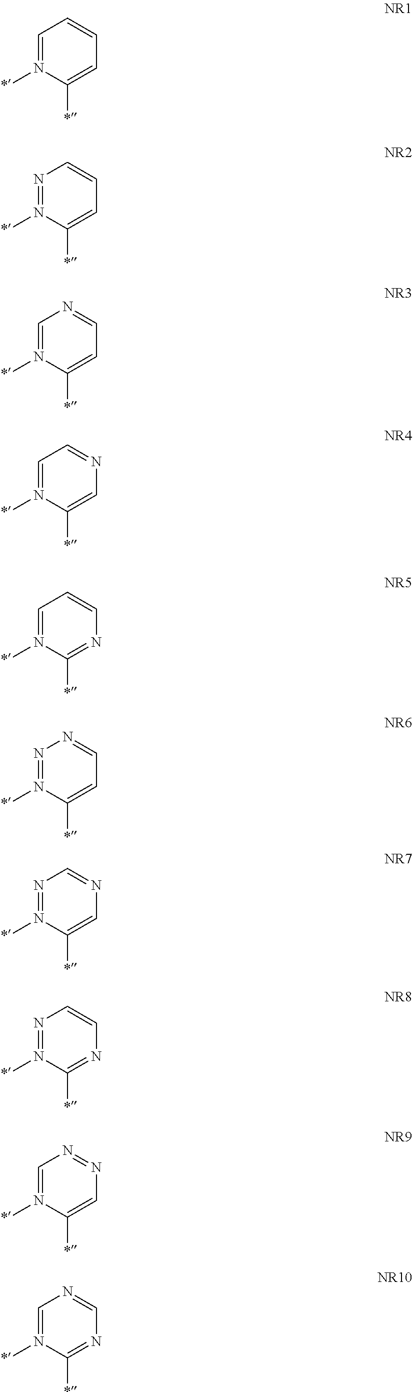

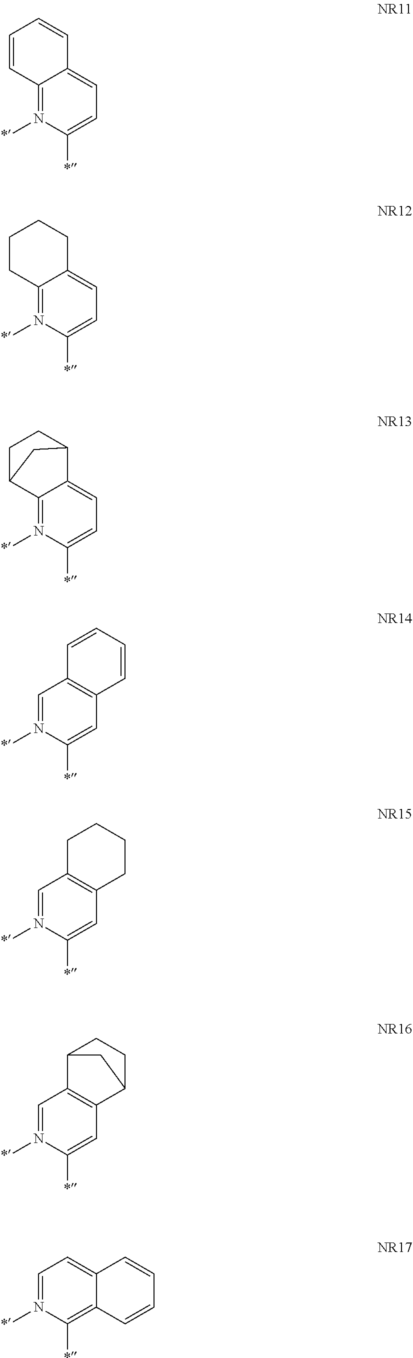

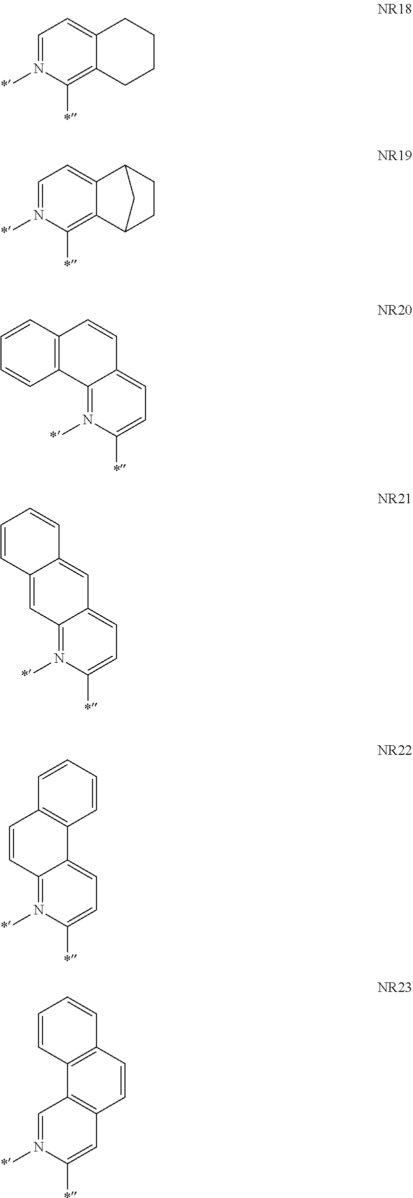

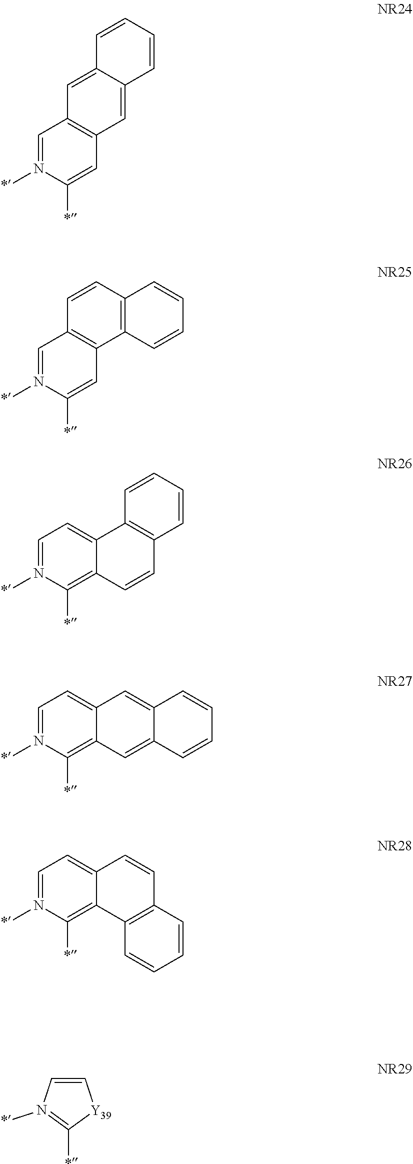

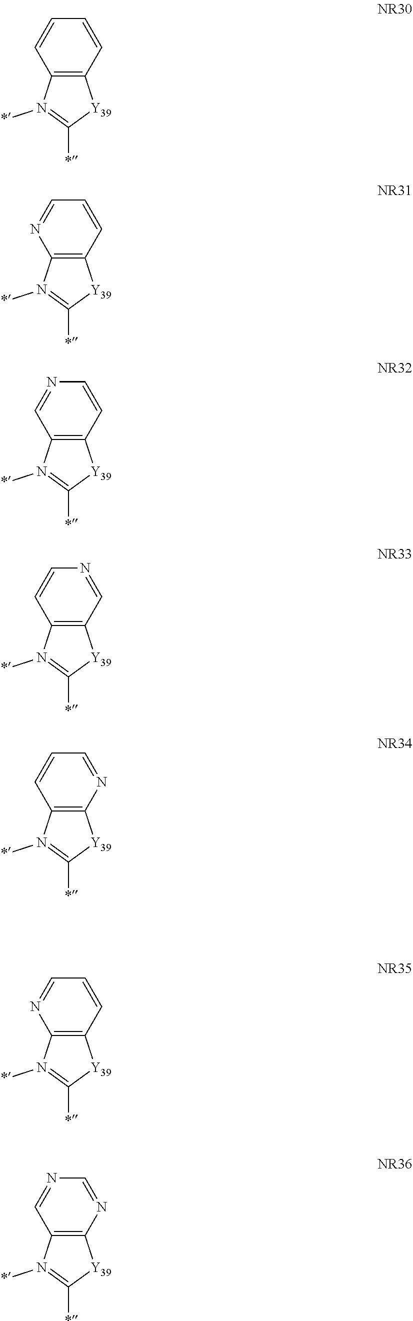

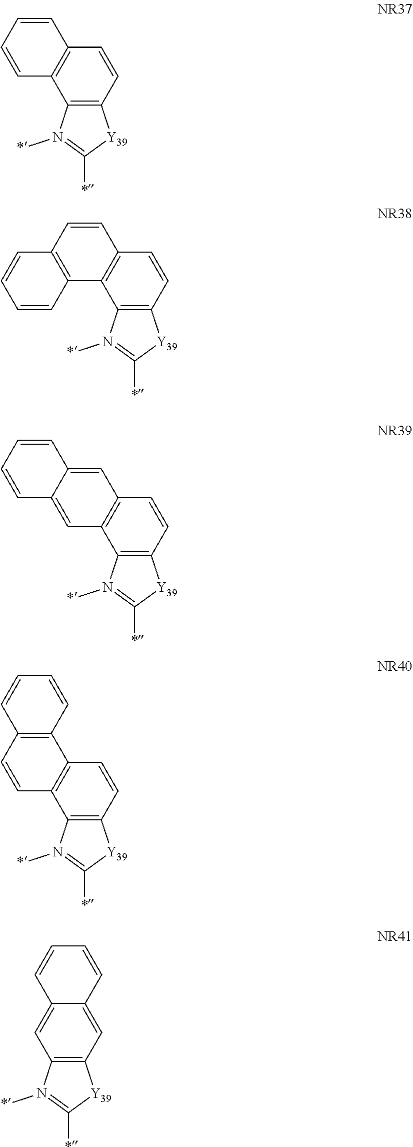

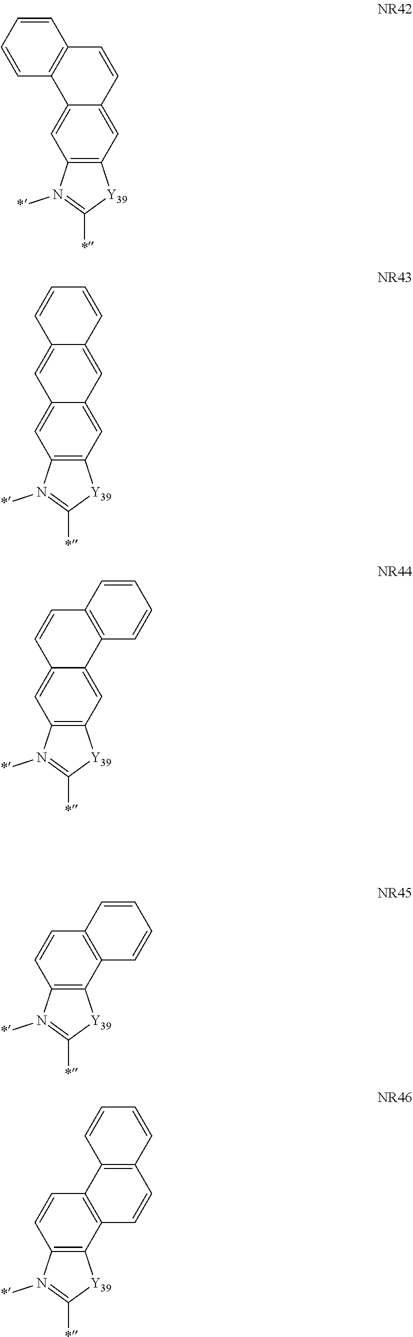

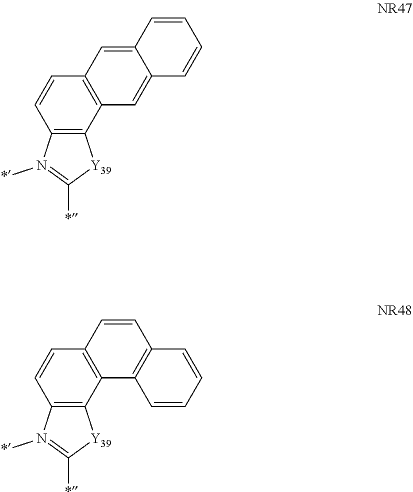

wherein, in Formulae NR1 to NR48,

Y₃₉ may be O, S, Se, N-[W₃—(Z₃)e₃], C(Z₃₉ₐ)(Z_{39b}), or Si(Z₃₉ₐ)(Z_{39b}),

W₃, Z₃, and e3 may each be as described herein, and Z₃₉ₐ and Z_{39b} may each be as described in connection with Z₃,

*′ indicates a binding site to M₂ in Formula 2, and

*″ indicates a binding site to ring A₄.

In one or more embodiments,

in Formulae 2-1 and 2-2, each of Y₂ and Y₄ may be C, and

a group represented by

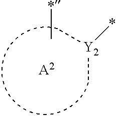

in Formula 2-1 and a group represented by

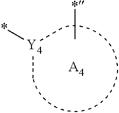

in Formula 2-2 may each independently be a group represented by one of Formulae CR1 to CR29:

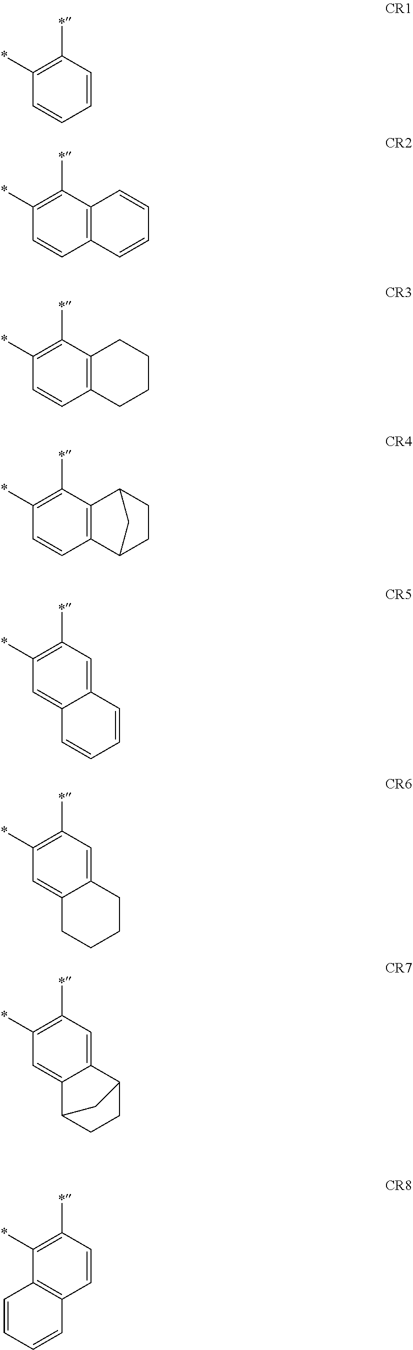

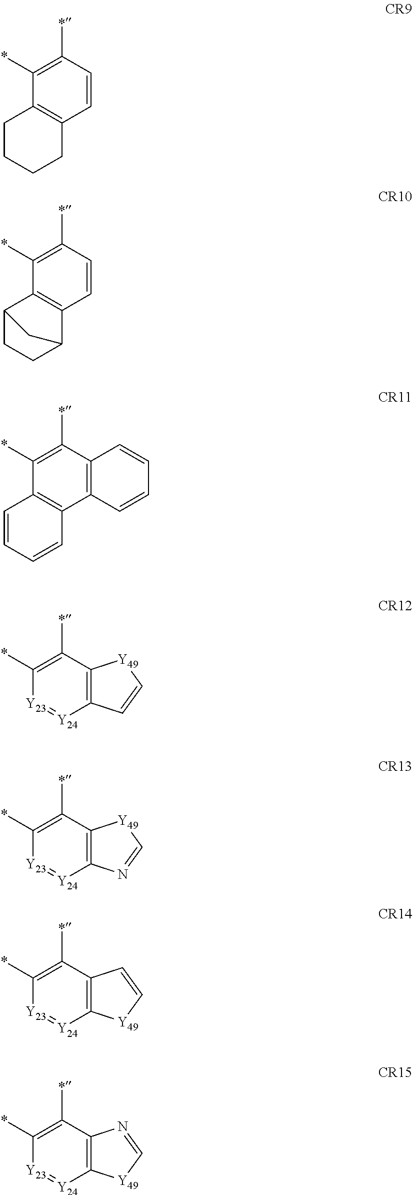

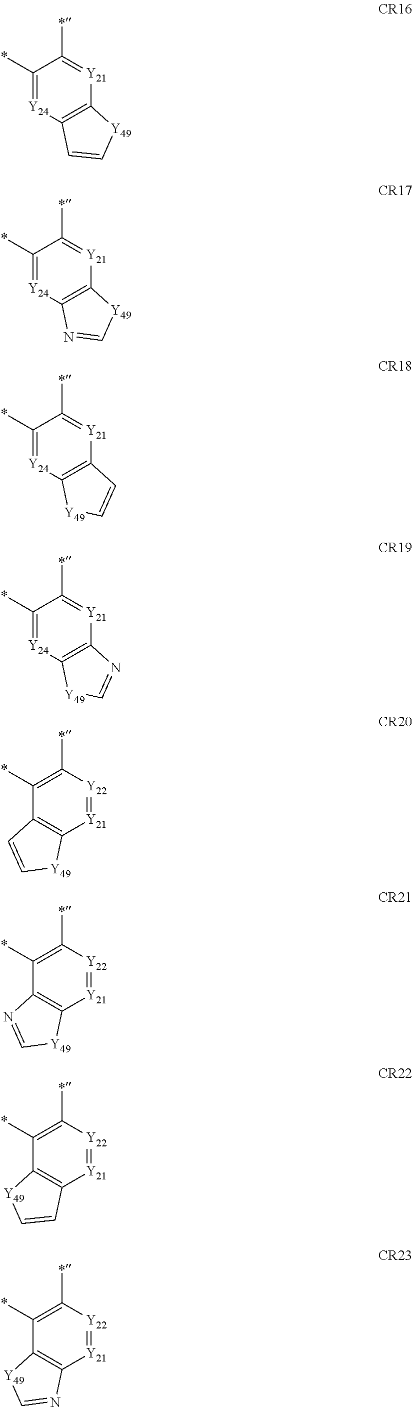

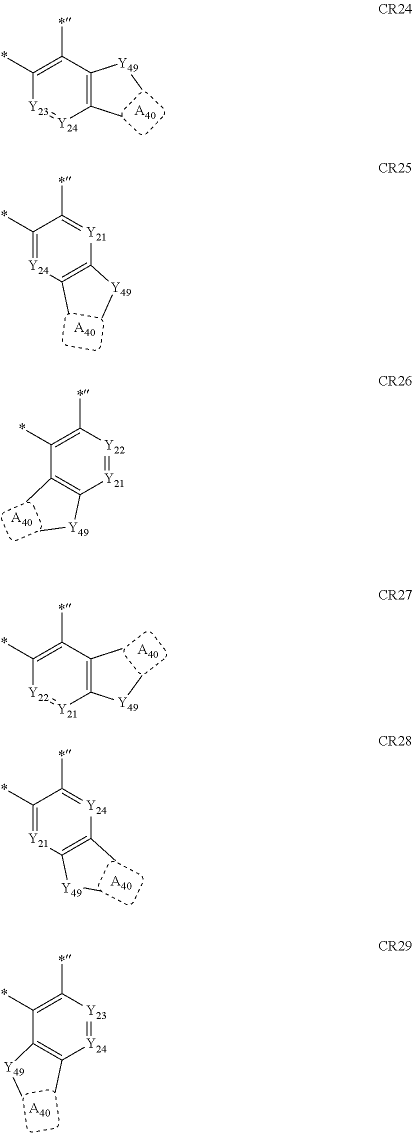

wherein, in CR1 to CR29,

Y₄₉ may be O, S, Se, N—[W₂—(Z₂)ₑ₂], N-[W₄—(Z₄)ₑ₄], C(Z₂₉ₐ)(Z_{29b}), C(Z₄₉ₐ)(Z_{49b}), Si(Z₂₉ₐ)(Z_{29b}), or Si(Z₄₉ₐ)(Z_{49b}),

W₂, W₄, Z₂, Z₄, e2, and e4 may each be as described herein, Z₂₉ₐ and Z_{29b} may each be as described in connection with Z₂, and Z₄₉ₐ and Z_{49b} may each be as described in connection with Z₄,

Y₂₁ to Y₂₄ may each independently be N or C,

ring A₄₀ may be a C₅-C₃₀ carbocyclic group or a C₁-C₃₀ heterocyclic group (for example, a benzene group, a naphthalene group, a phenanthrene group, a pyridine group, a pyrimidine group, a pyrazine group, a pyridazine group, a quinoline group, an isoquinoline group, a benzoquinoline group, a benzoisoquinoline group, a quinoxaline group, a benzoquinoxaline group, a quinazoline group, or a benzoquinazoline group),

* indicates a binding site to M₂ in Formula 2, and

*″ indicates a binding site to ring A₁ or ring A₃ in Formula 1.

In one or more embodiments,

a group represented by

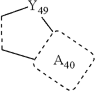

in Formulae CR24 to CR29 may be a group represented by one of Formulae CR(1) to CR(13):

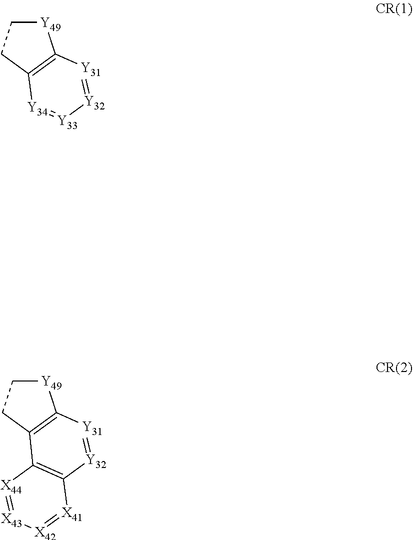

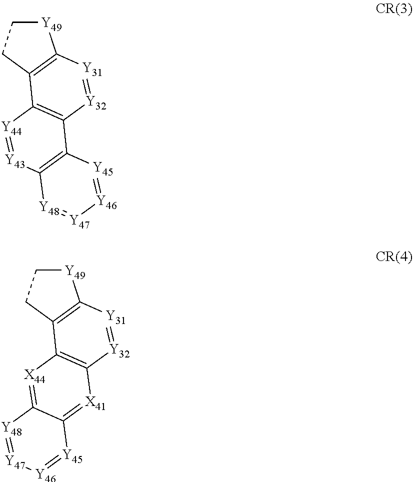

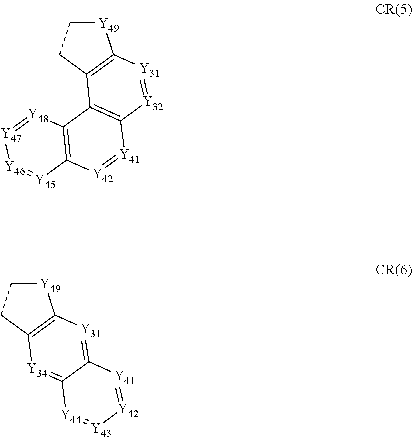

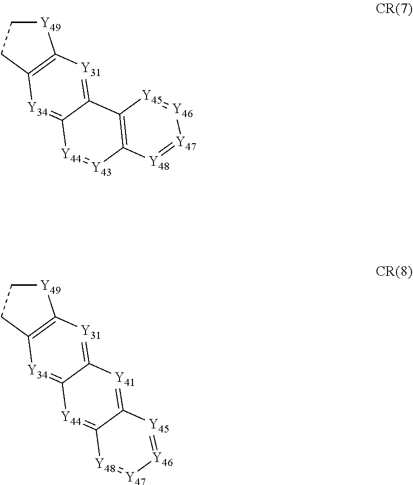

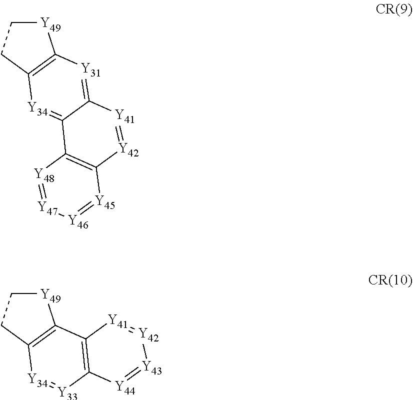

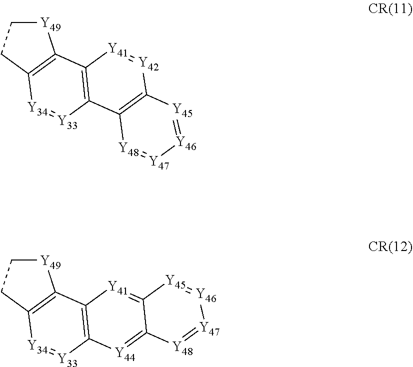

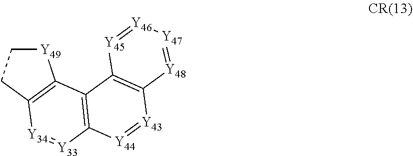

wherein, in Formulae CR(1) to CR(13),

Y₄₉ may be as described herein, and

Y₃₁ to Y₃₄ and Y₄₁ to Y₄₈ may each independently be C or N.

In one or more embodiments, the first compound may include at least one deuterium.

In one or more embodiments, the second compound may include at least one deuterium.

For example, the first compound may be a compound of Group 1-1 to Group 1-4:

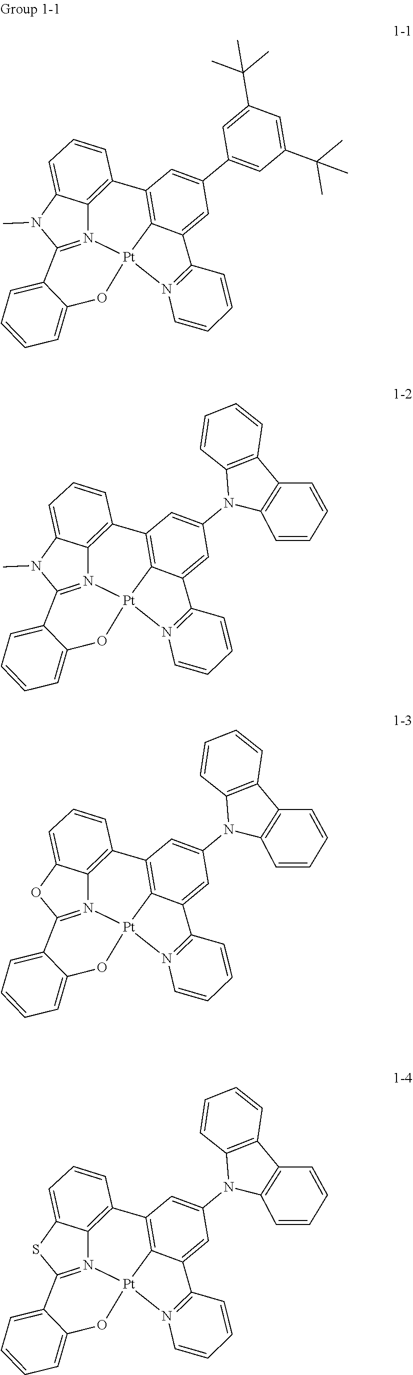

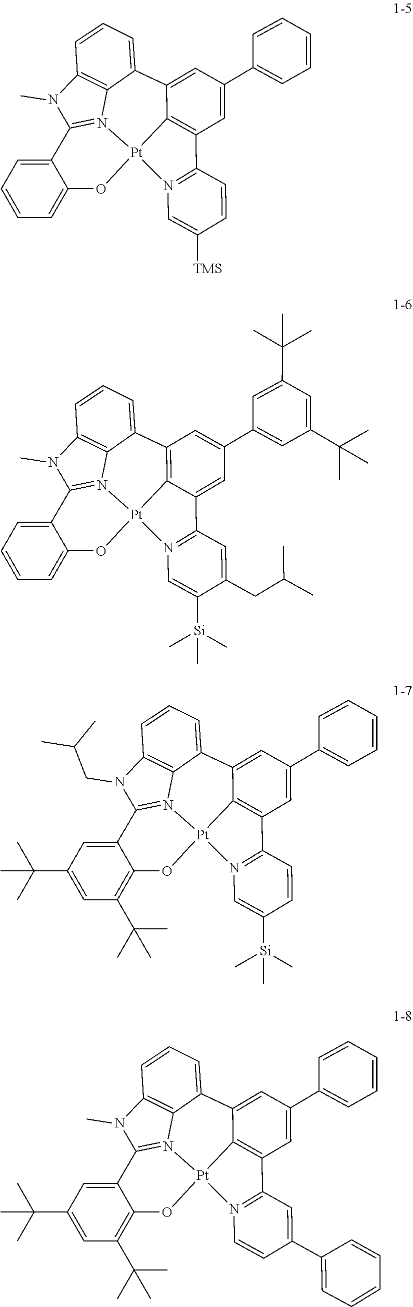

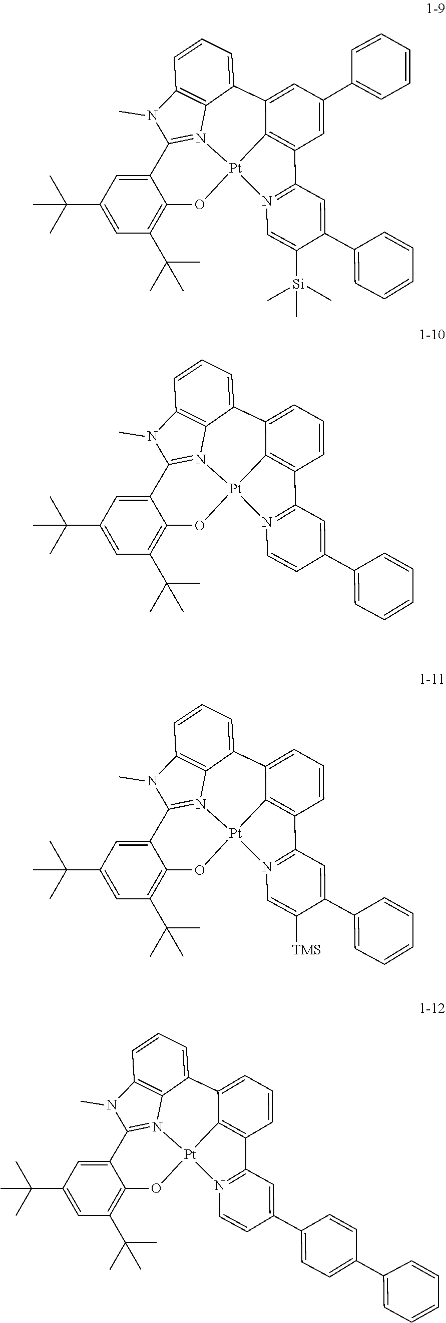

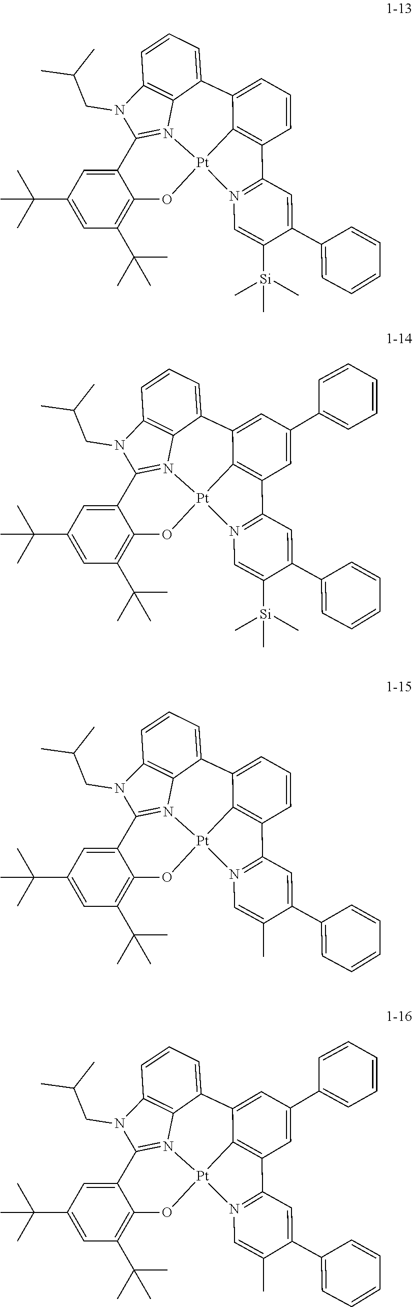

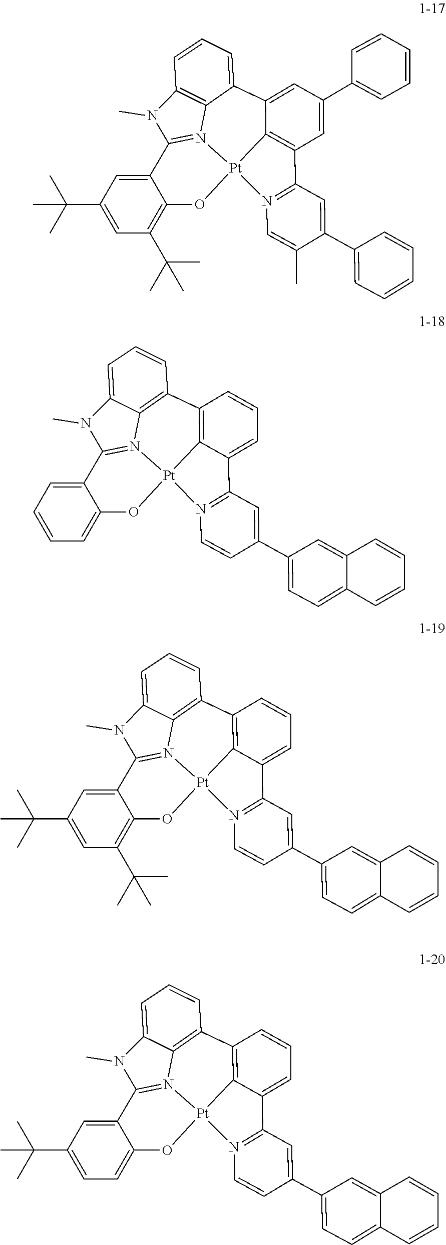

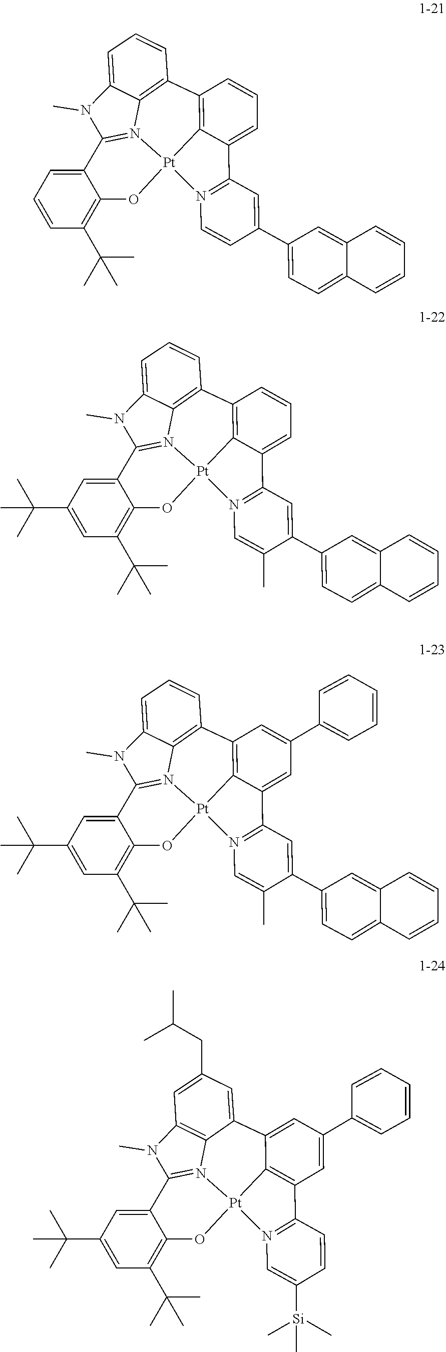

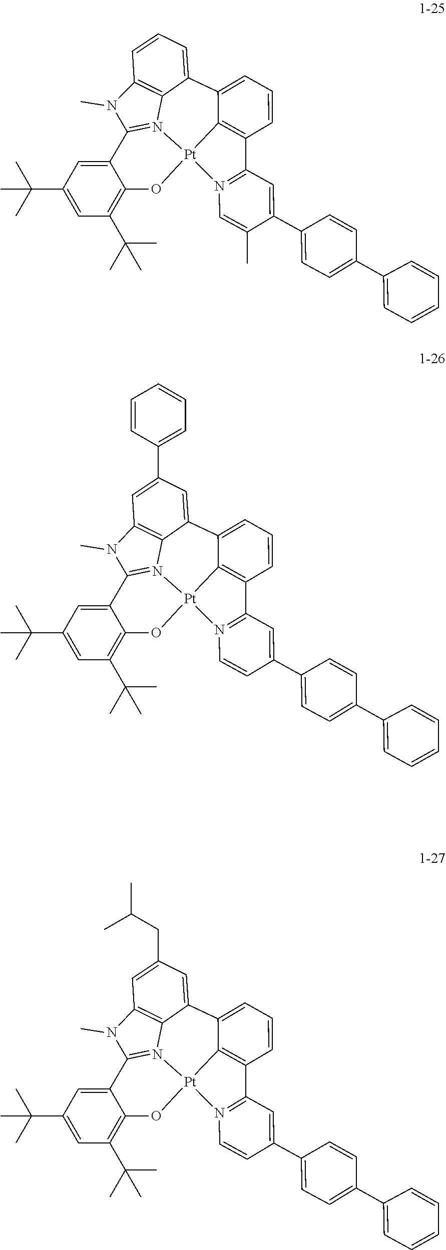

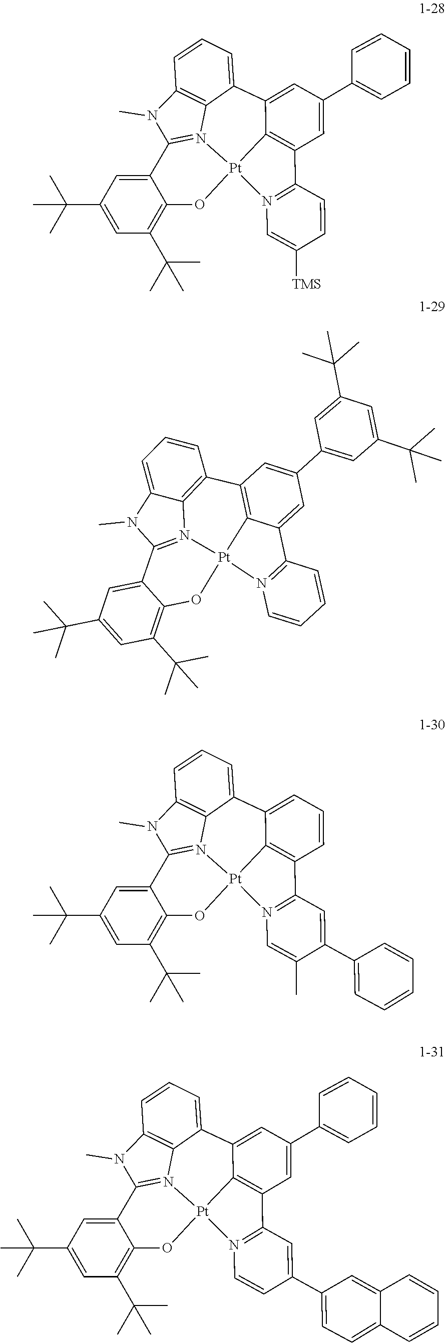

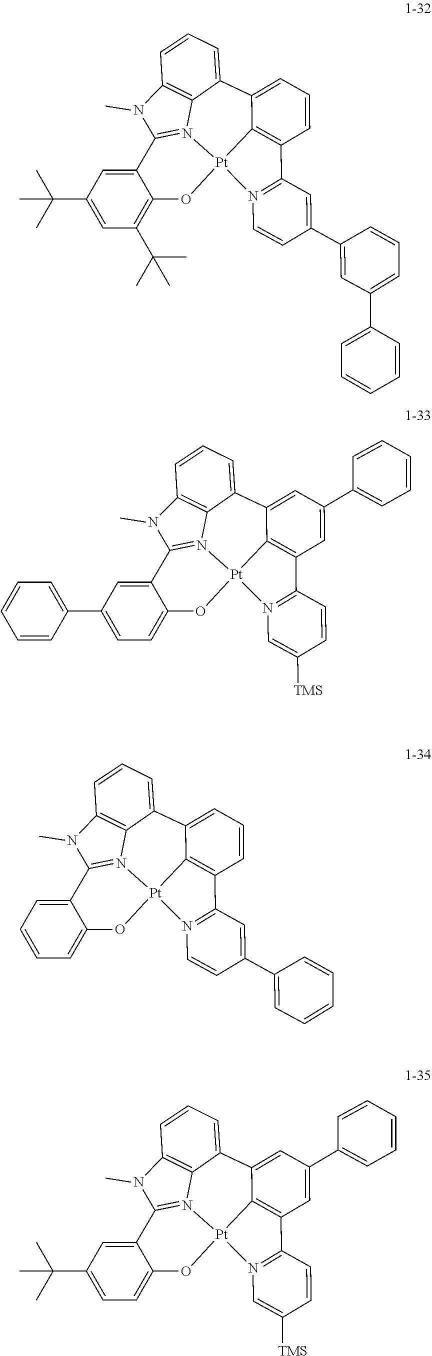

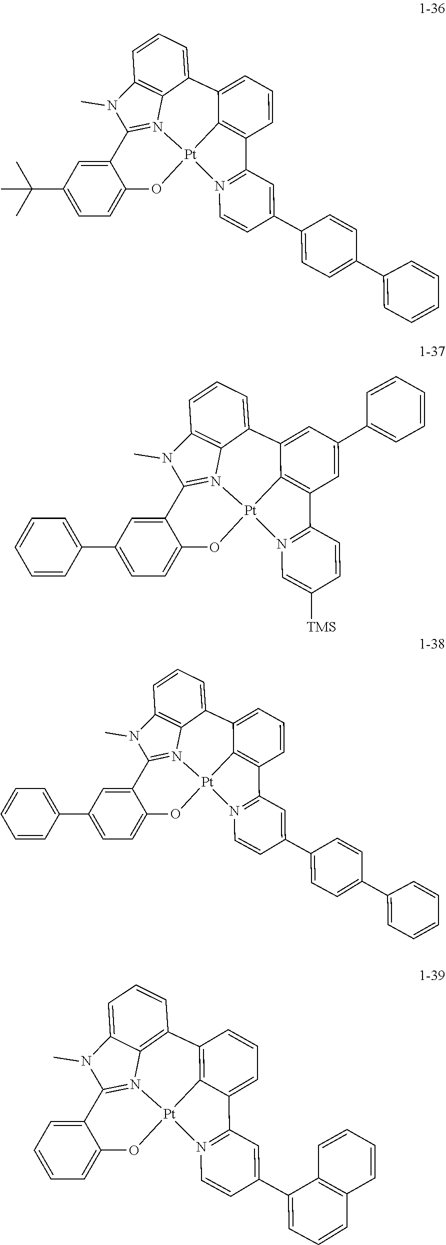

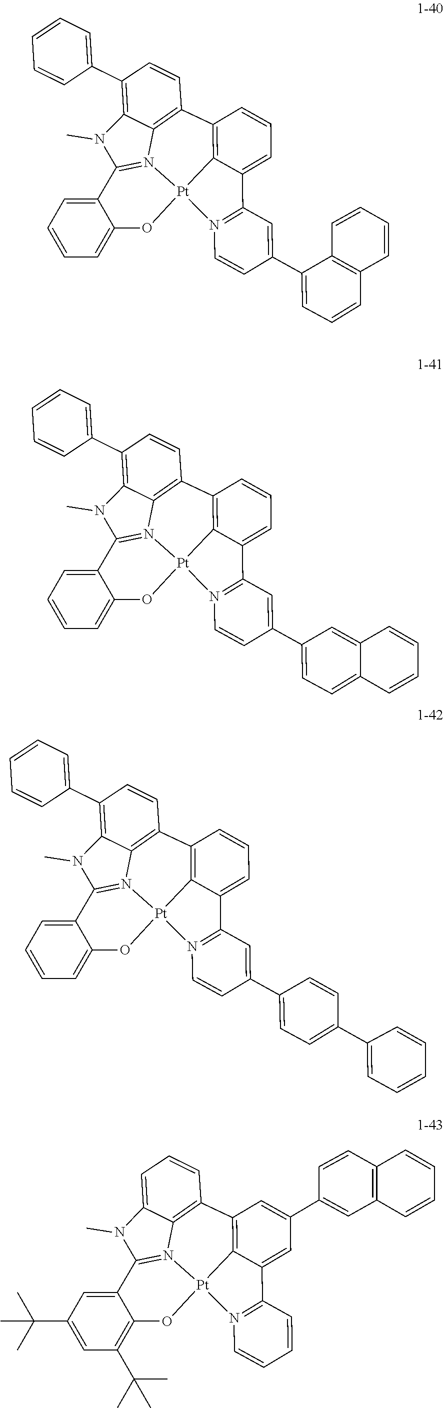

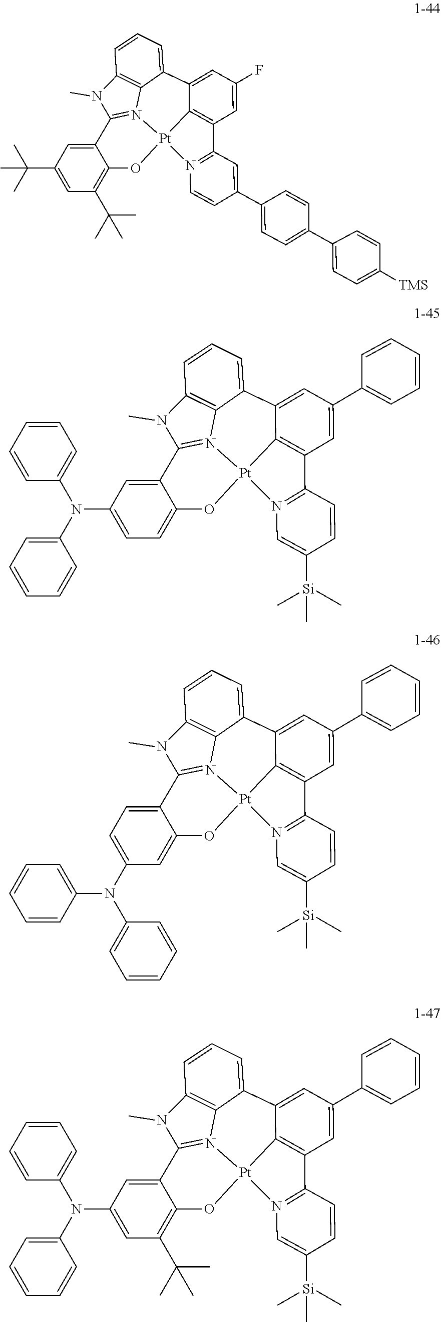

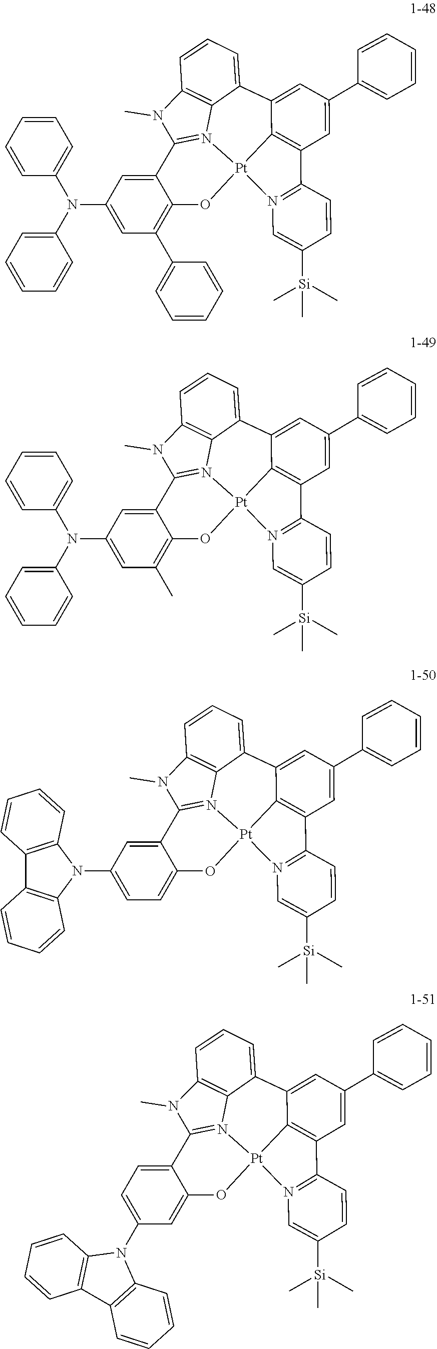

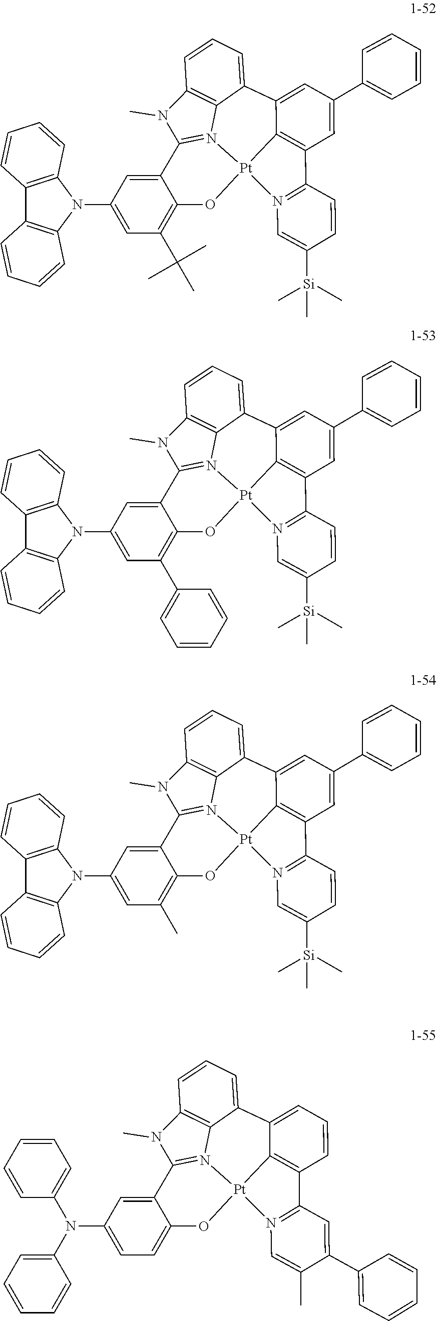

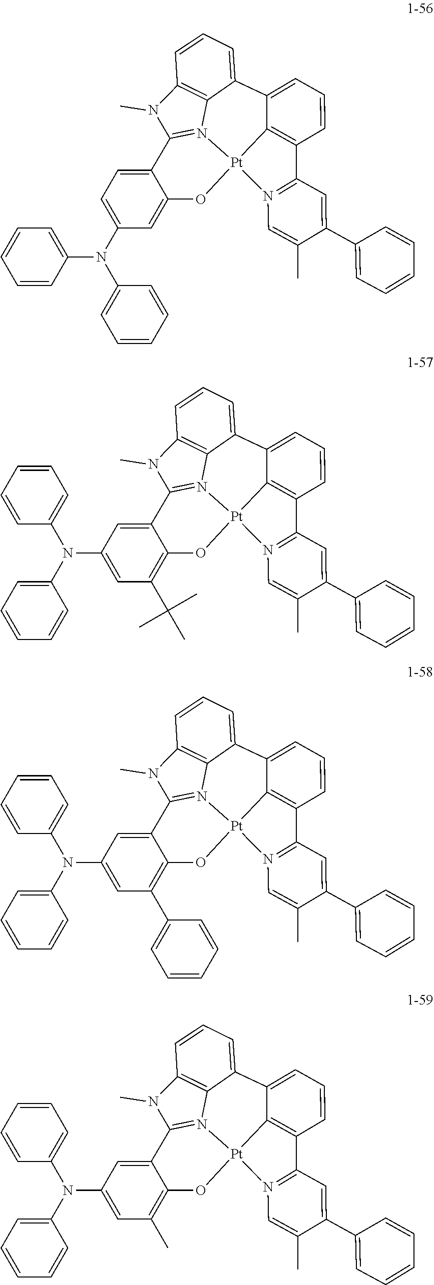

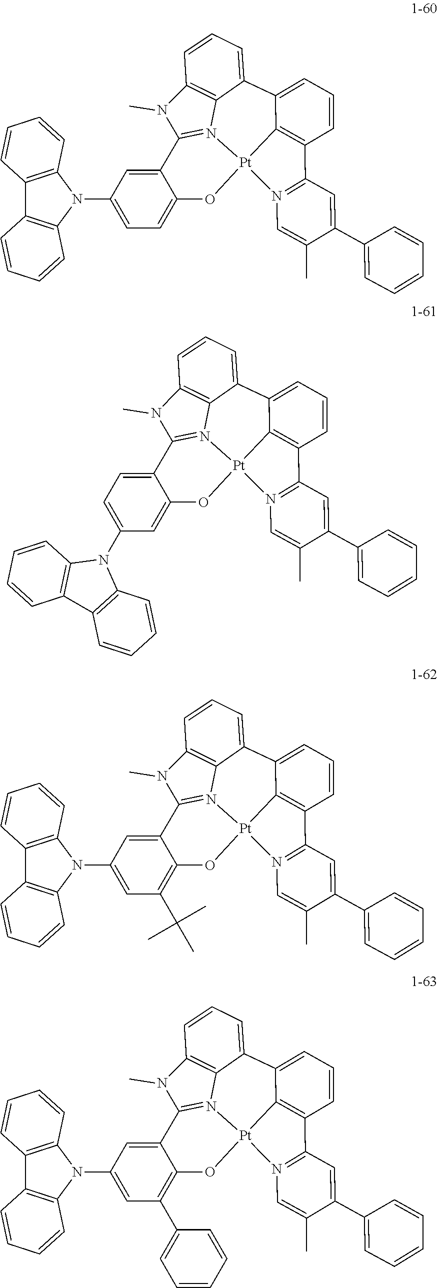

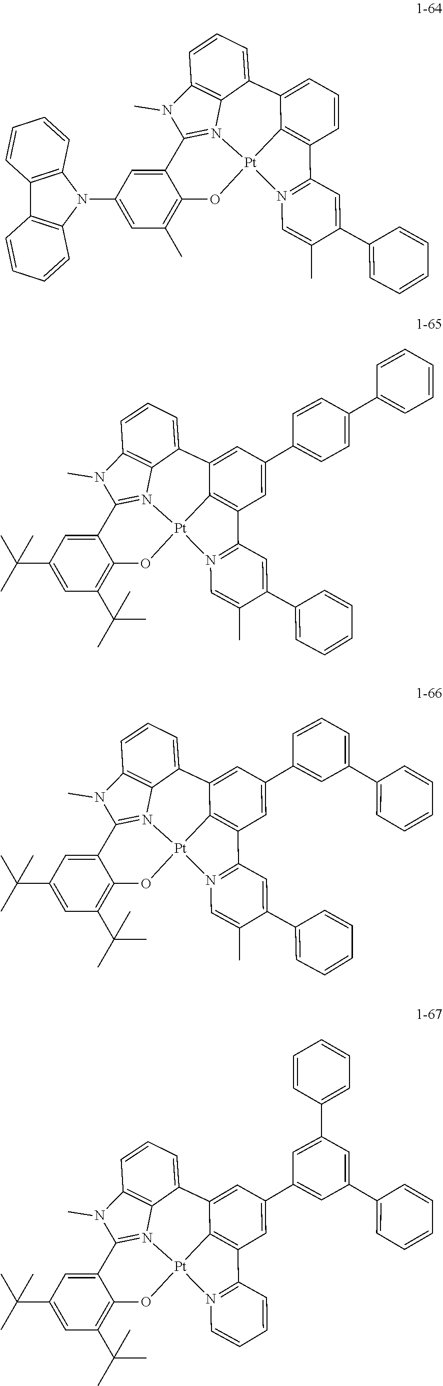

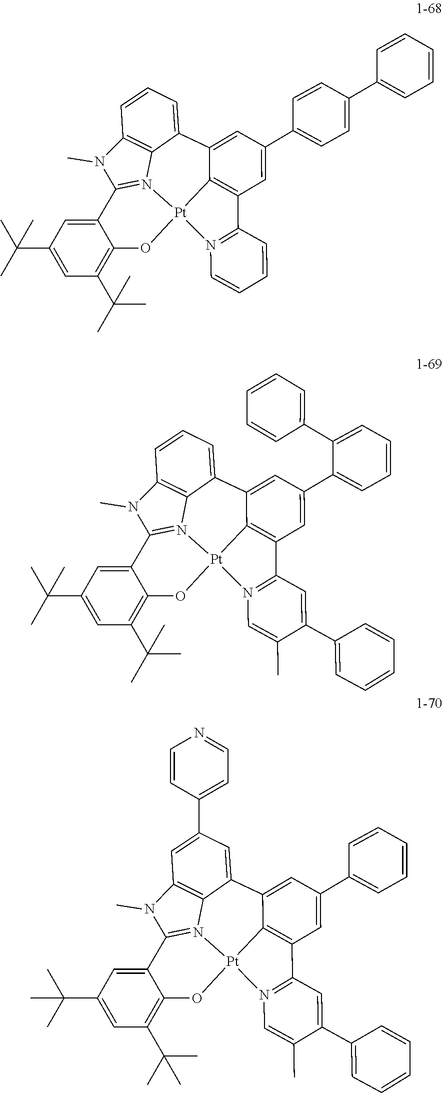

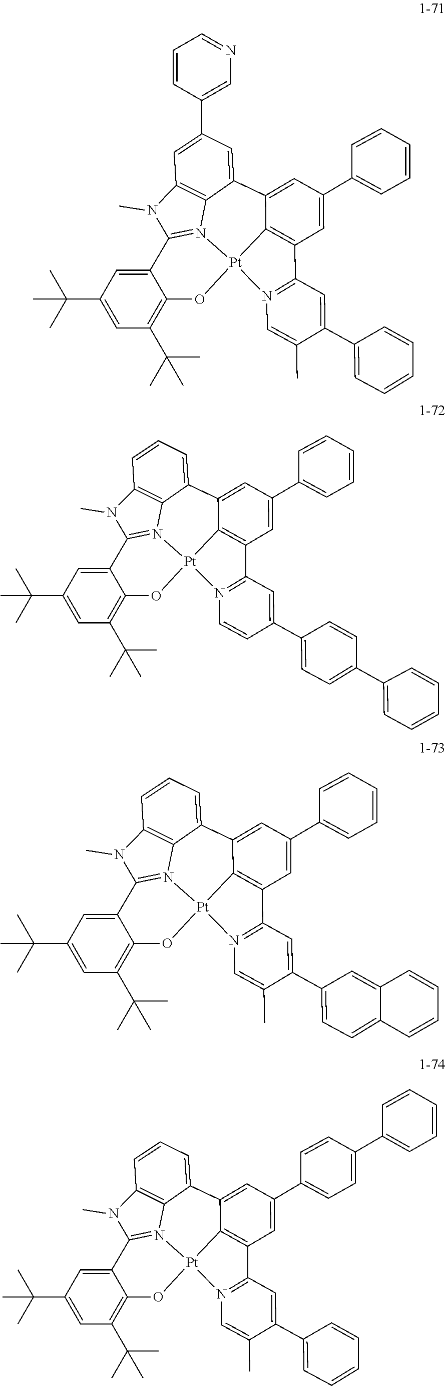

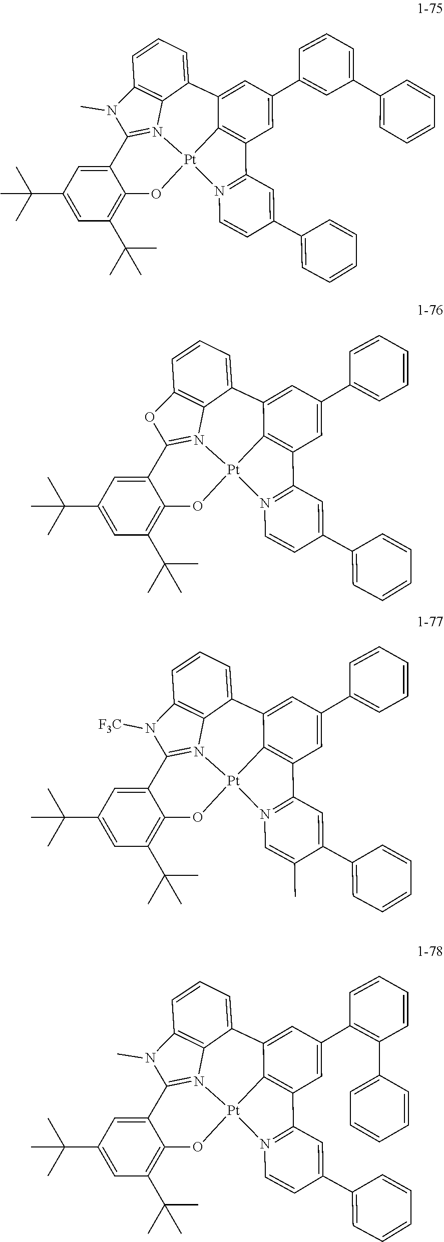

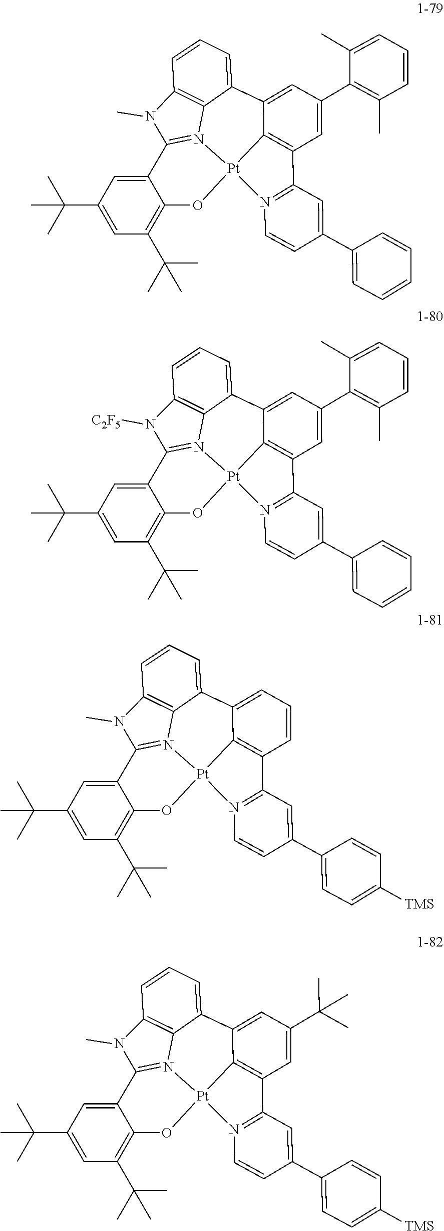

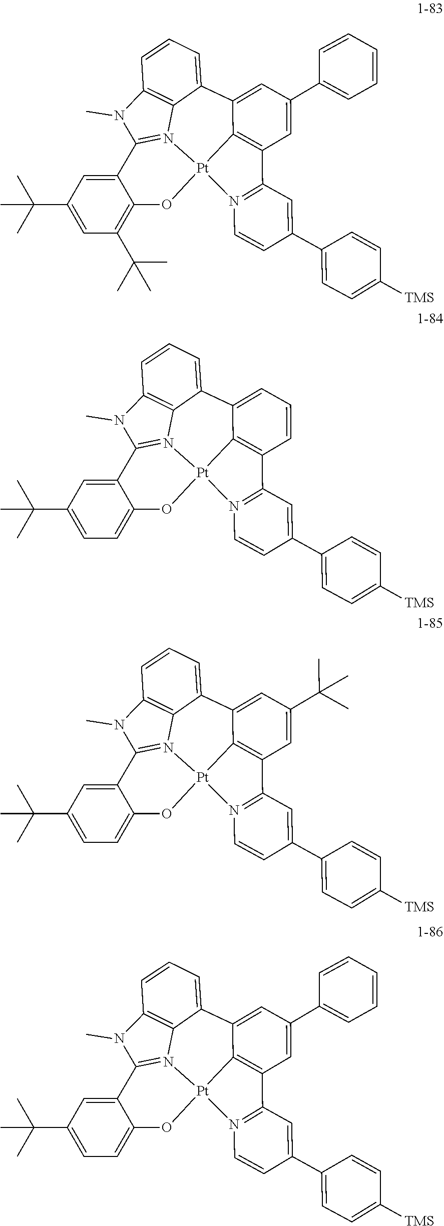

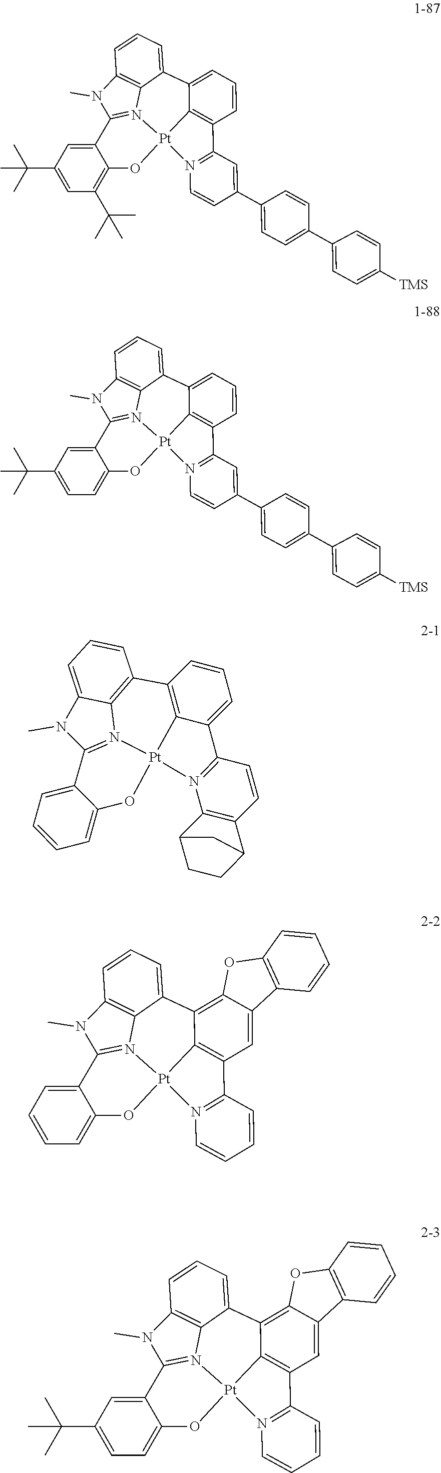

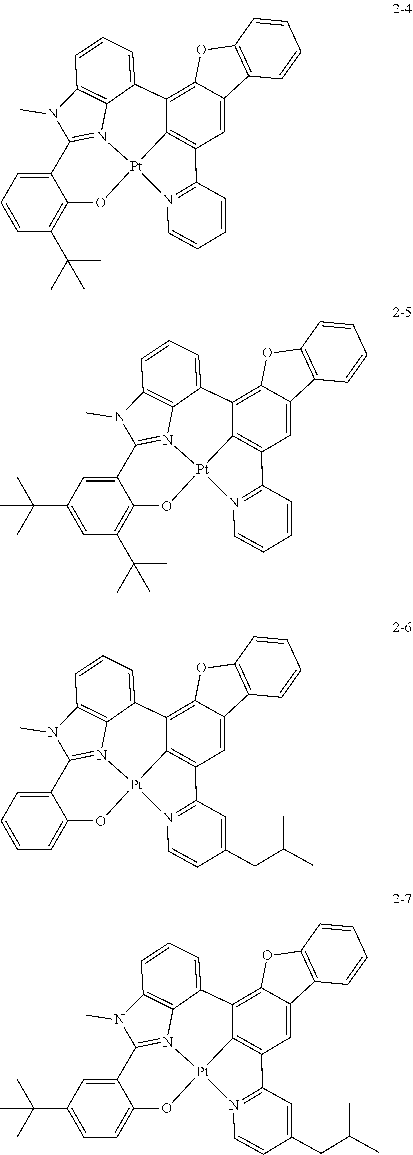

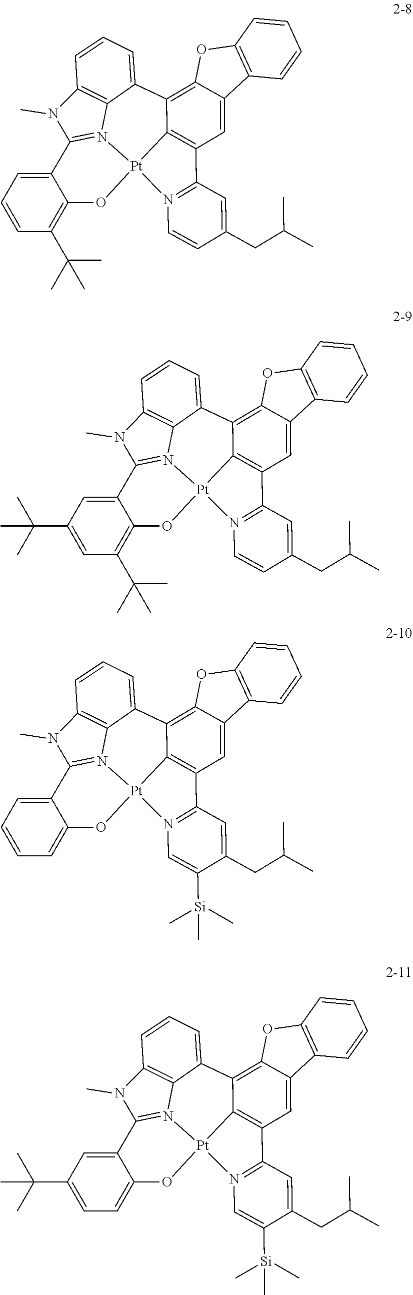

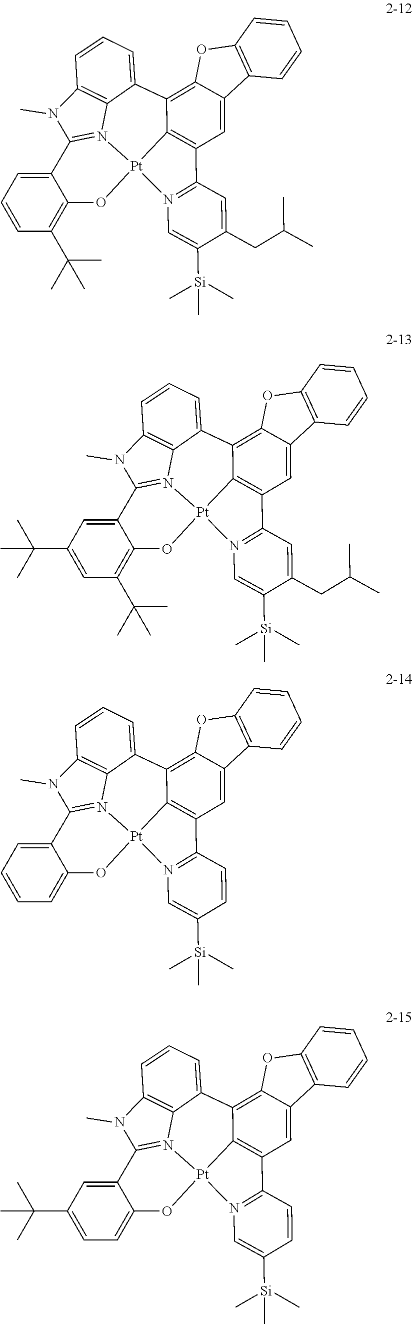

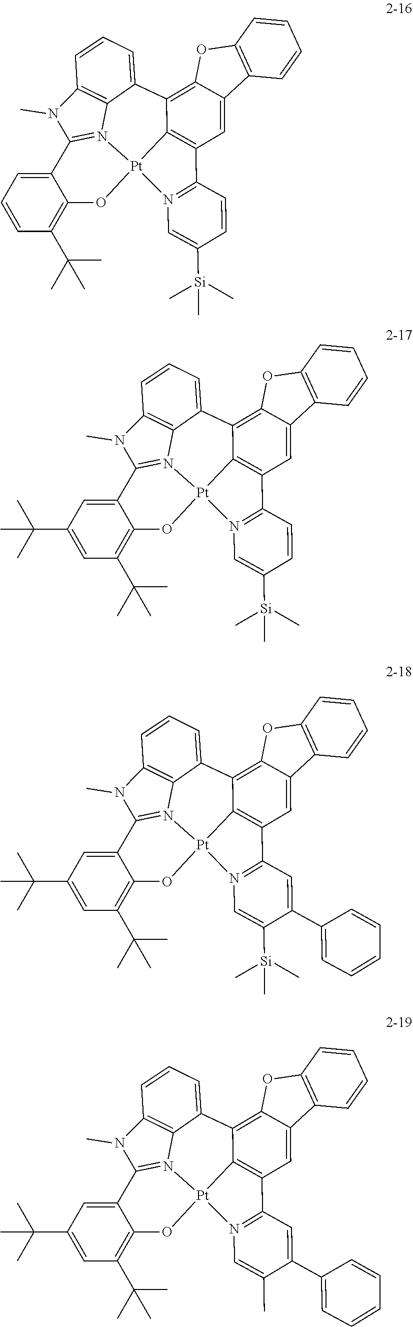

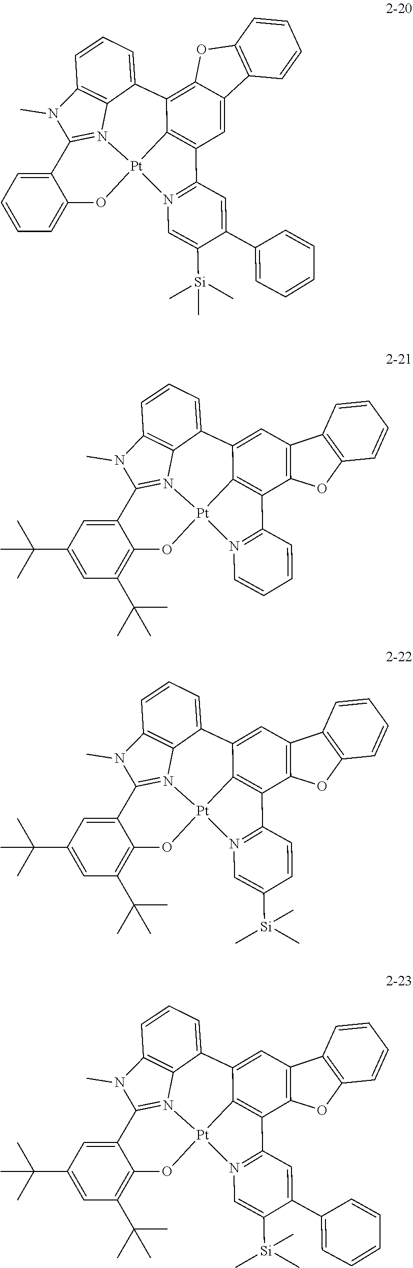

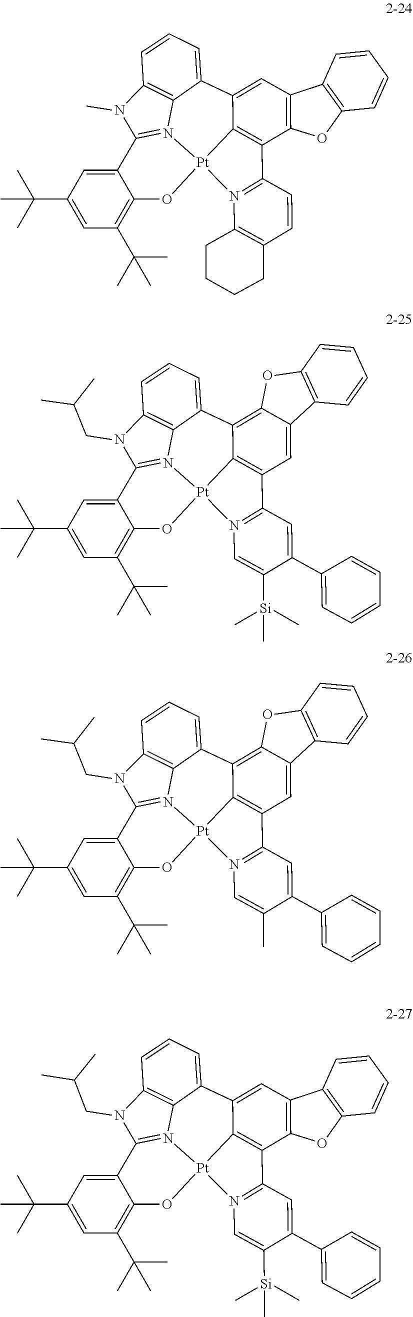

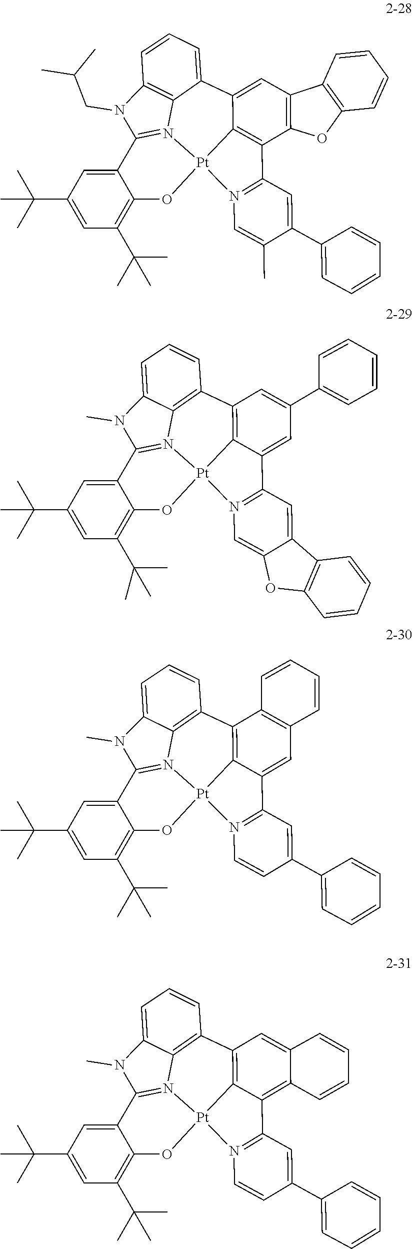

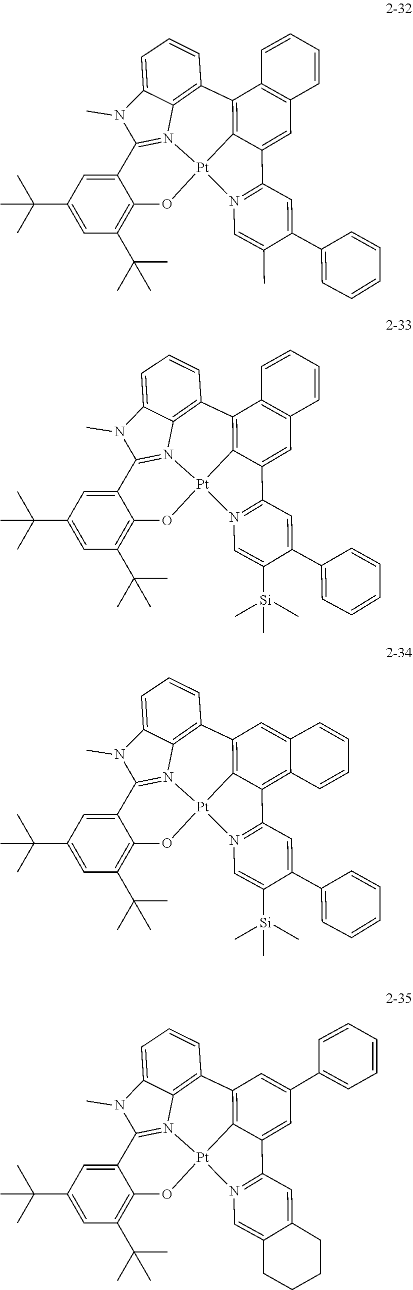

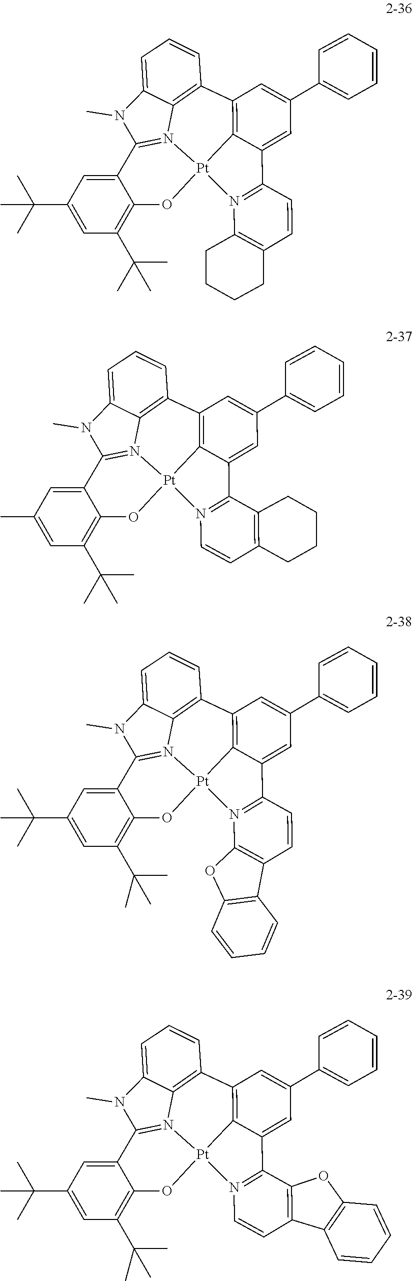

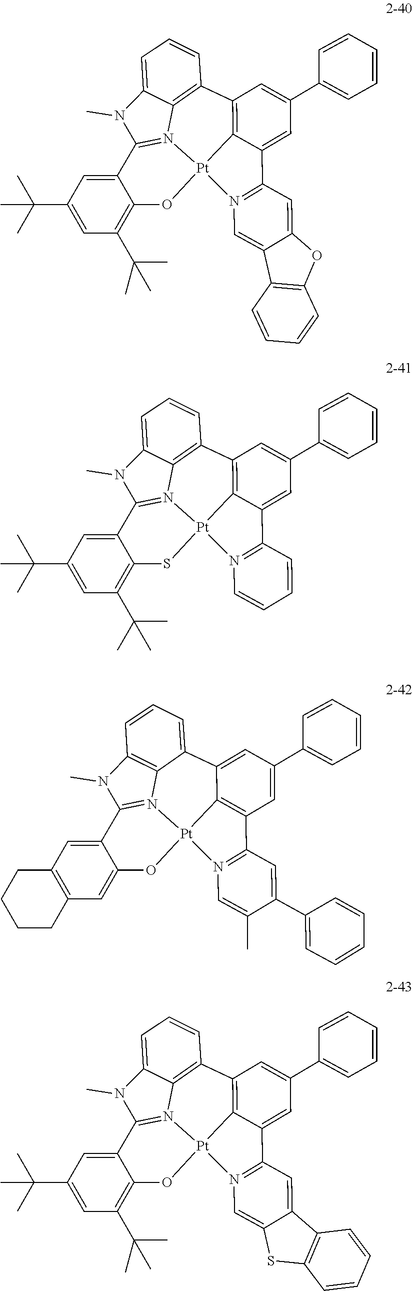

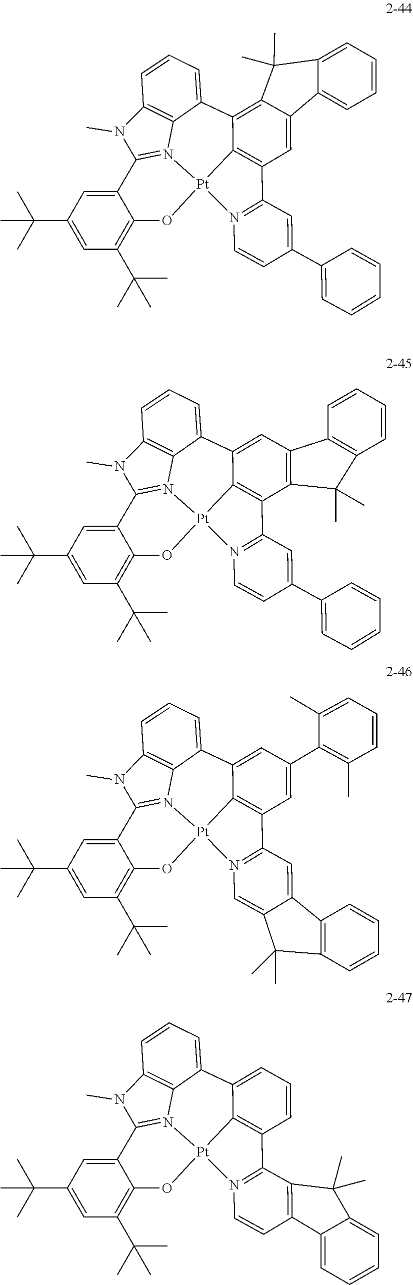

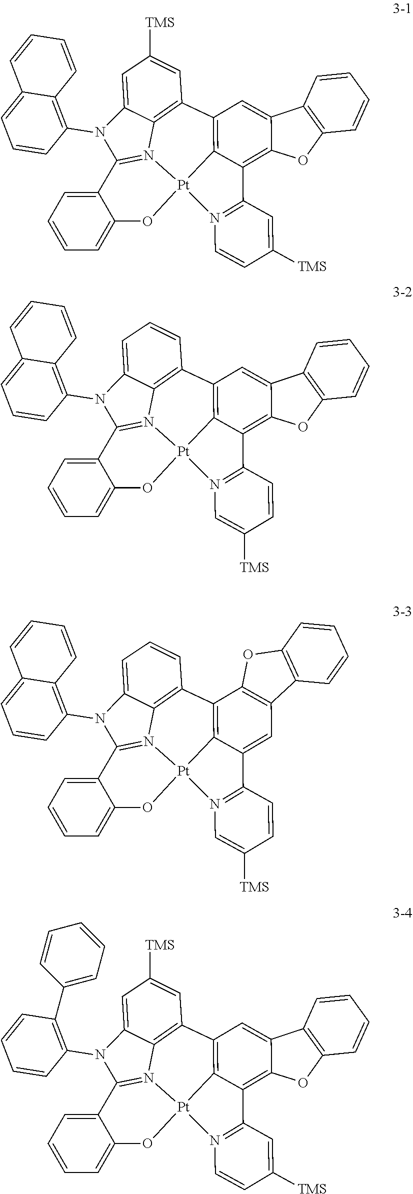

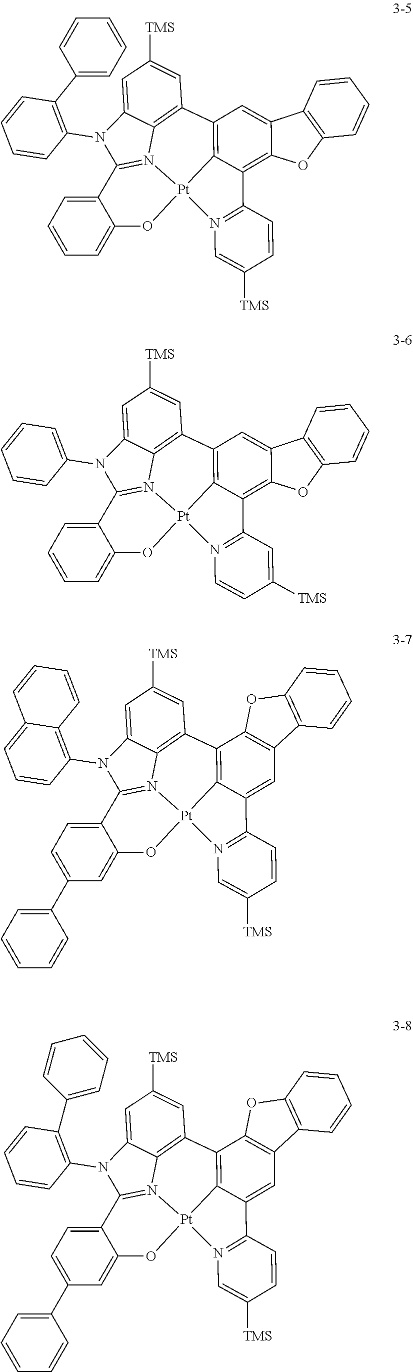

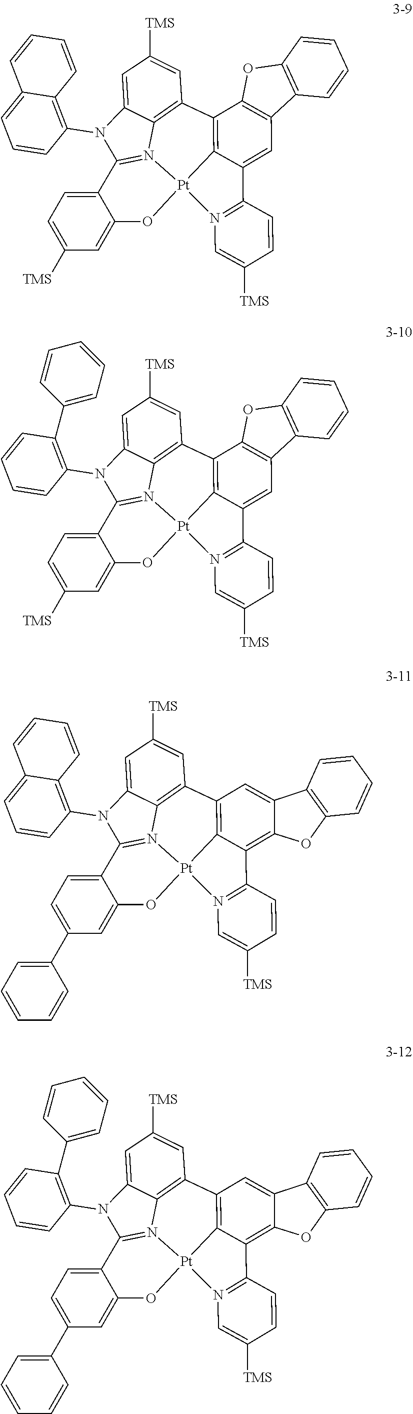

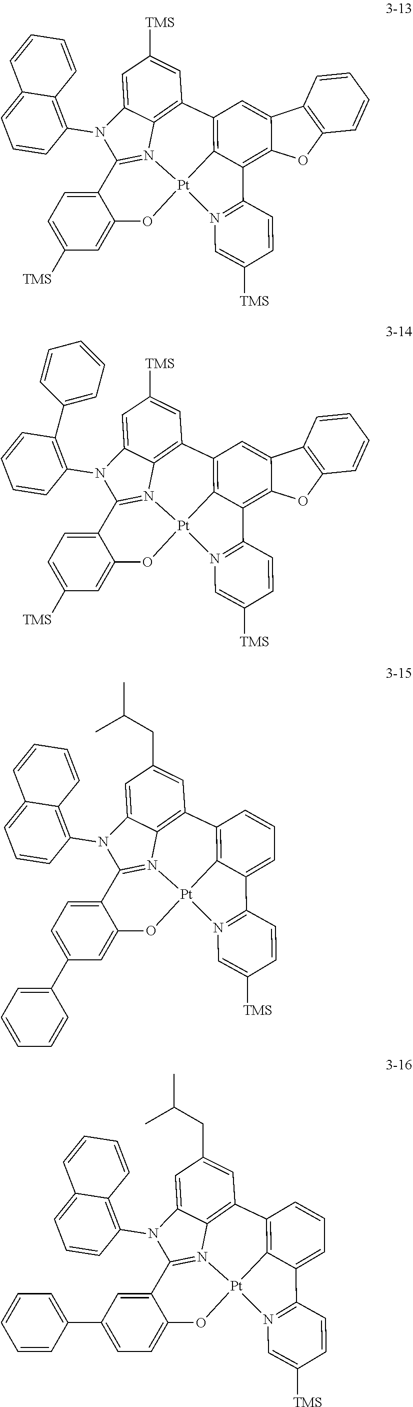

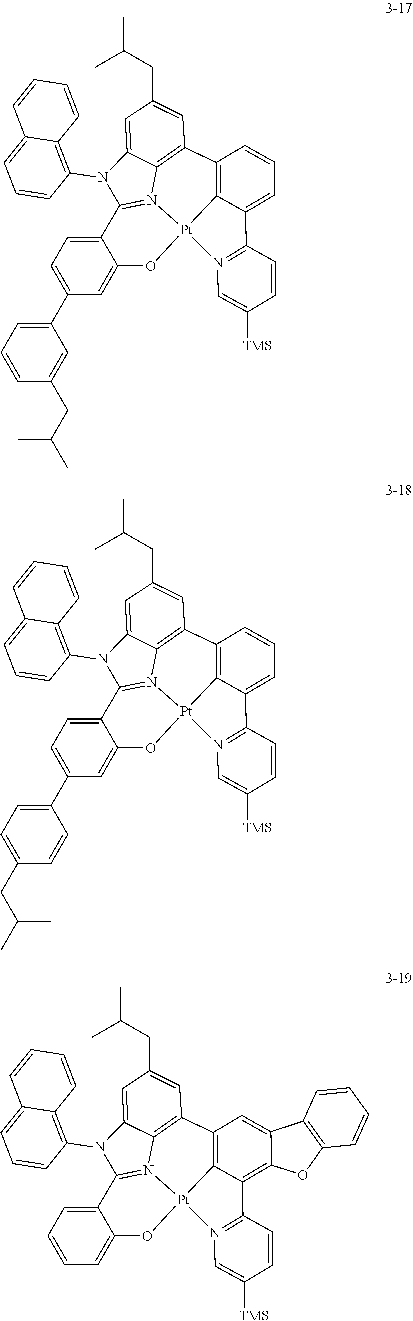

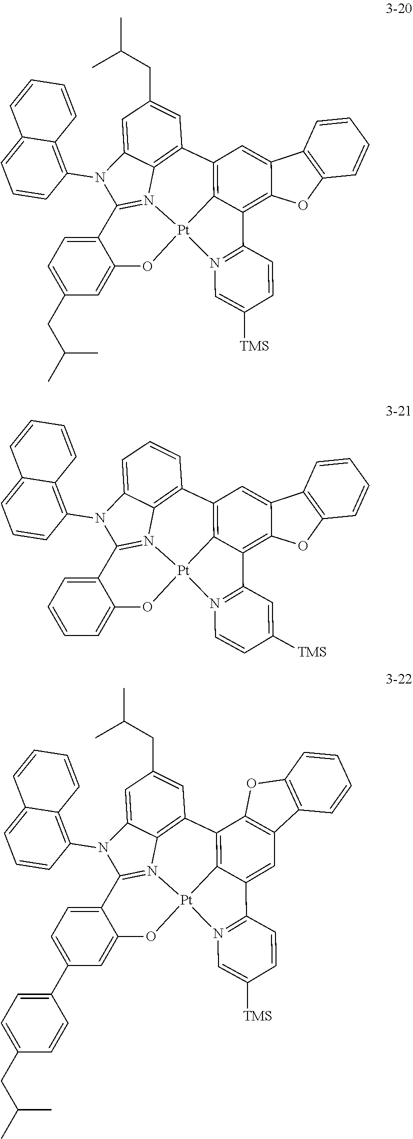

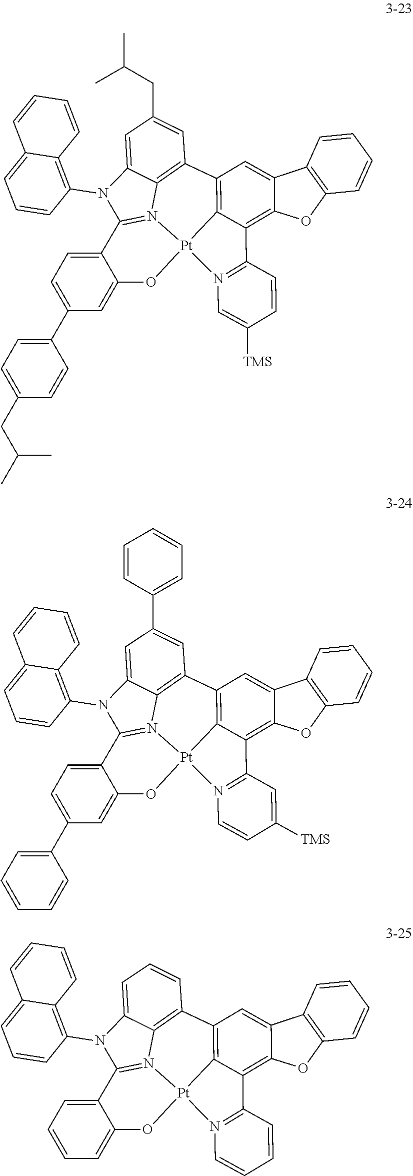

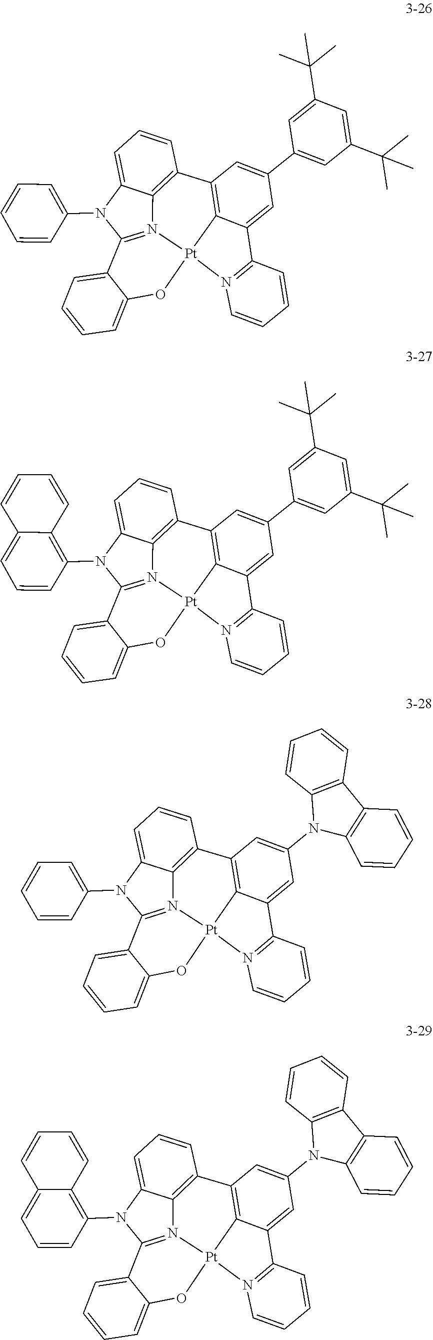

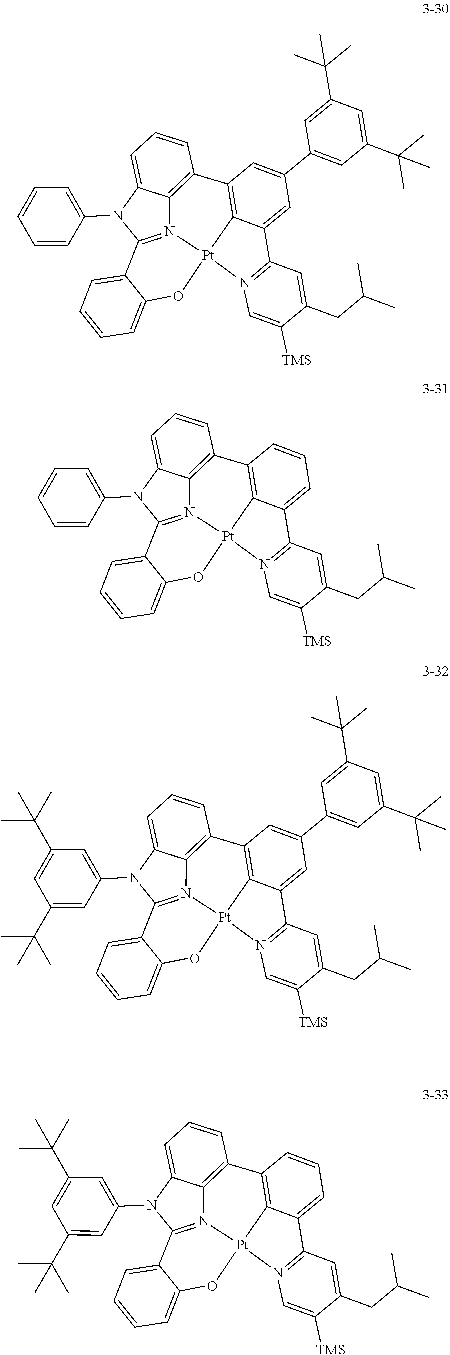

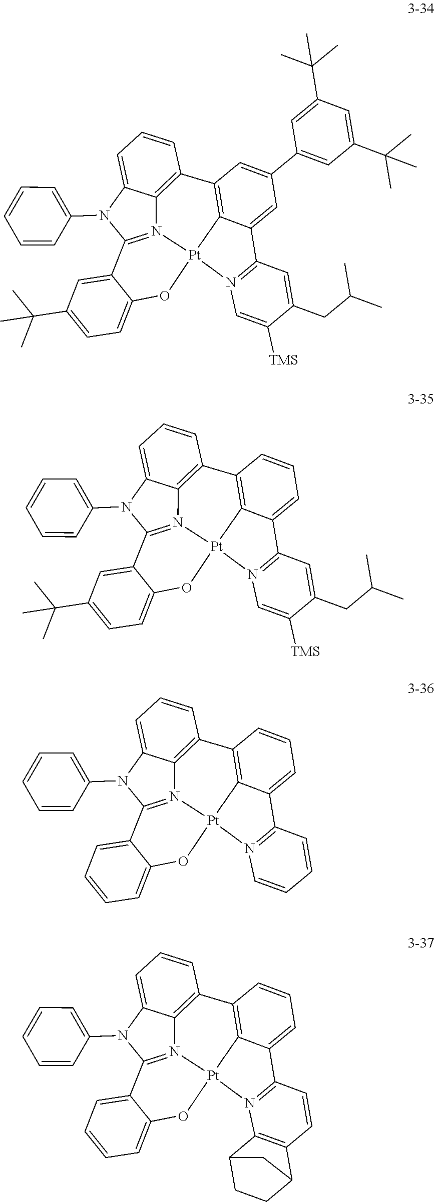

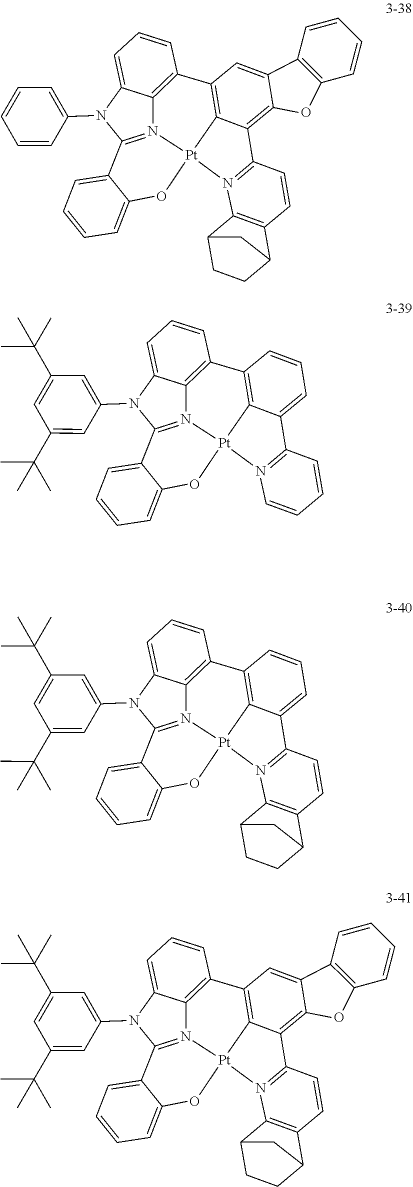

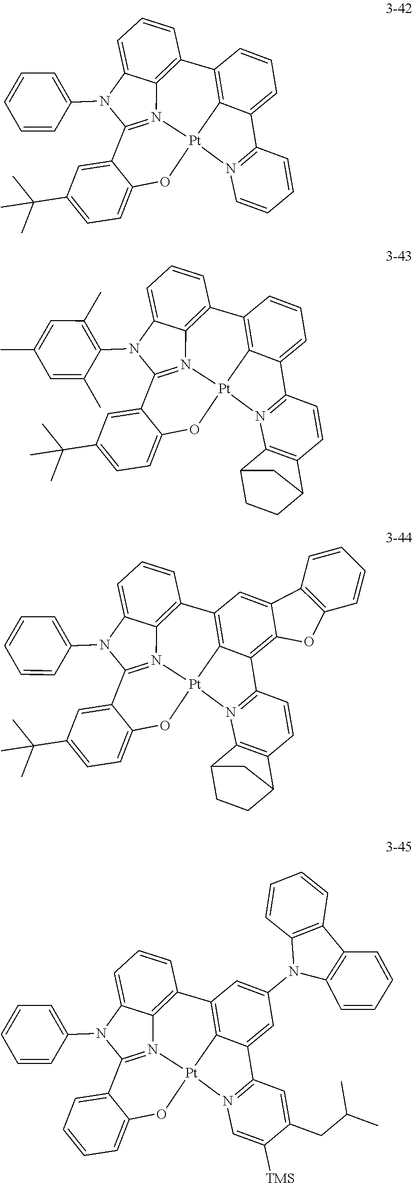

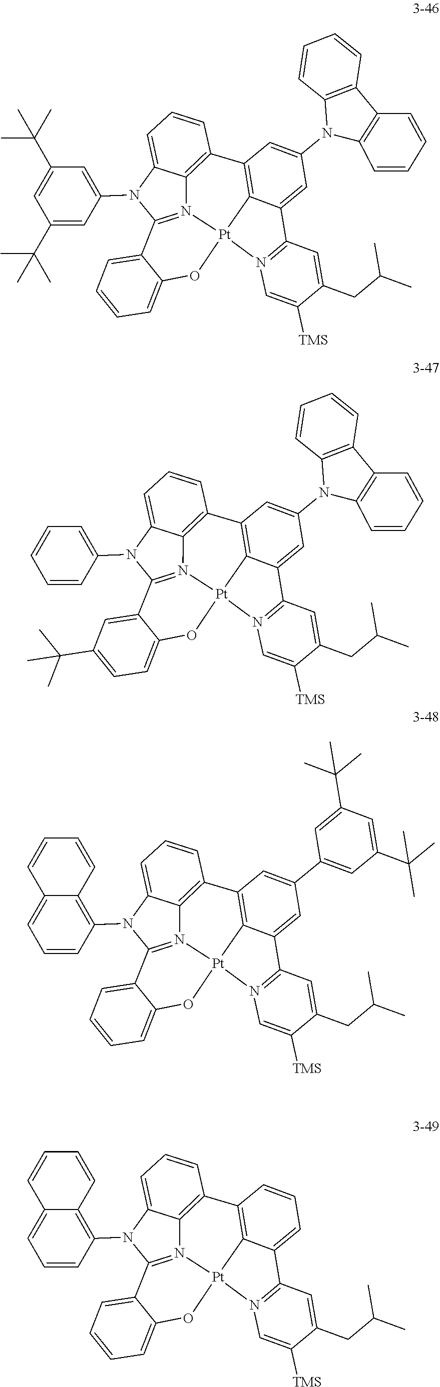

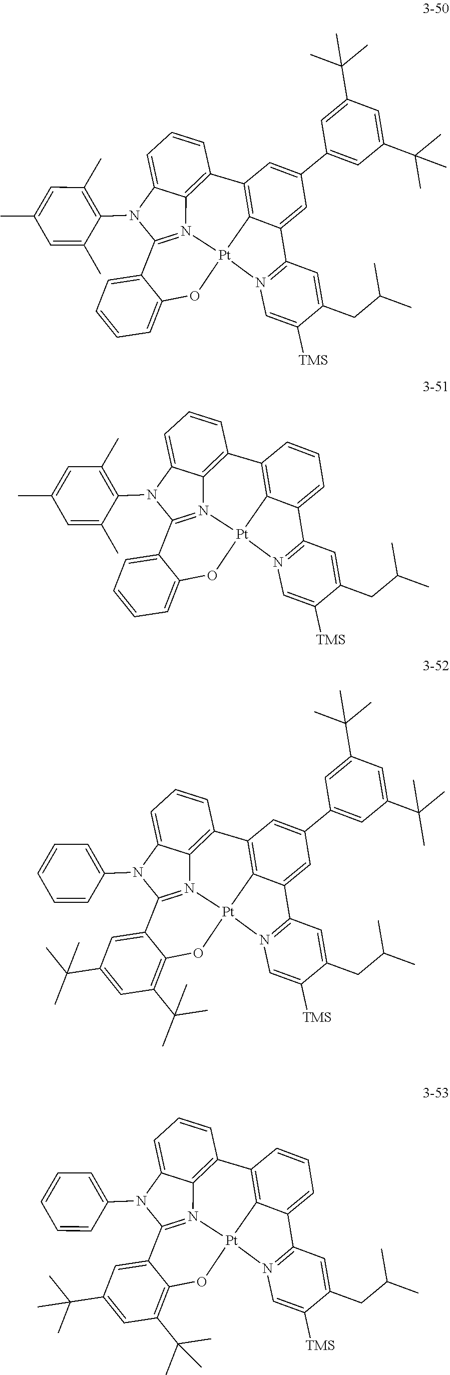

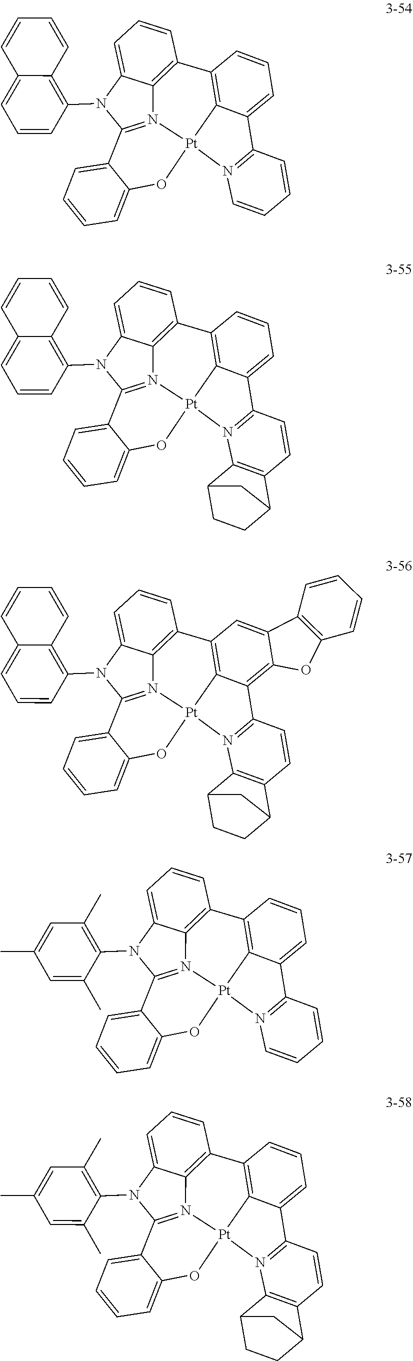

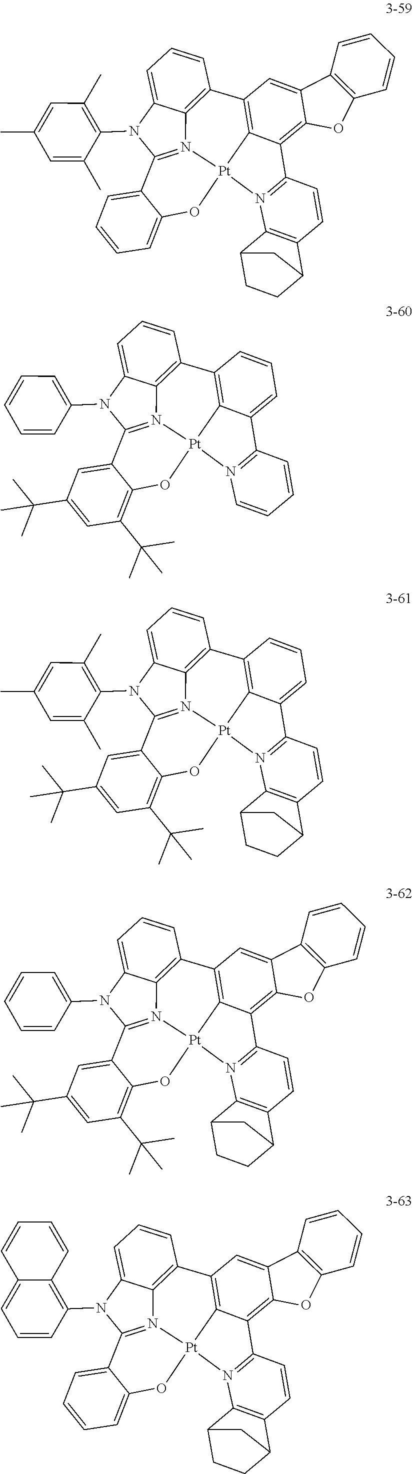

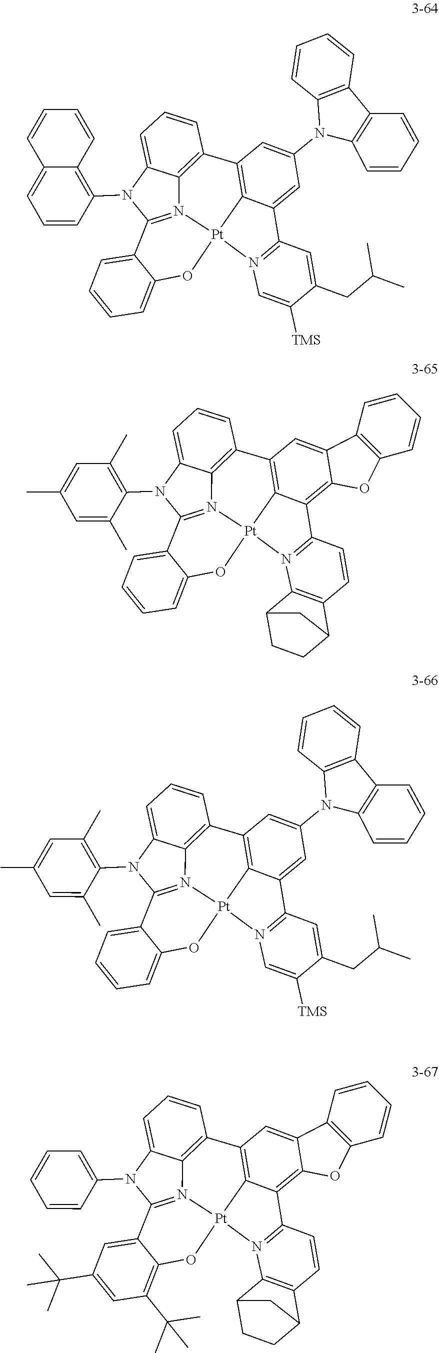

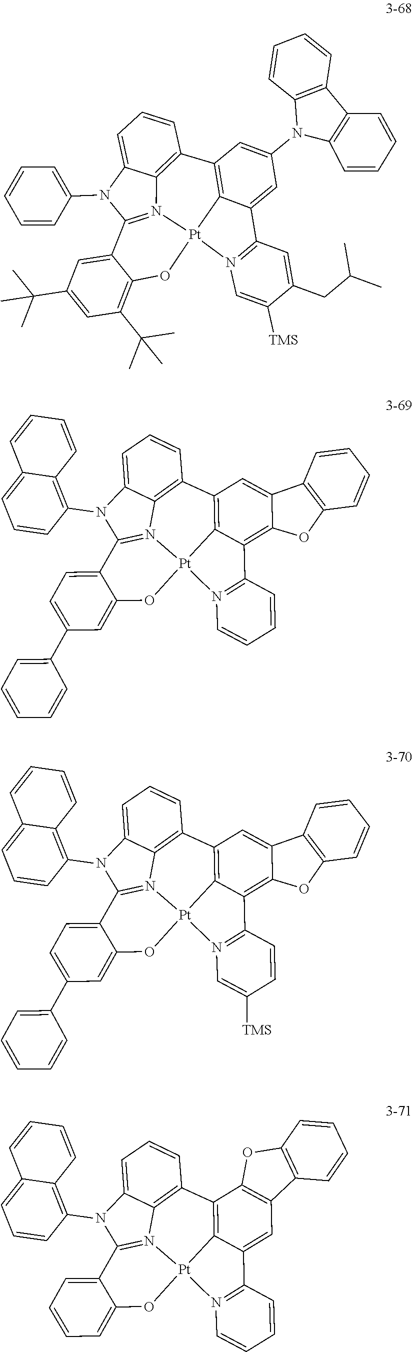

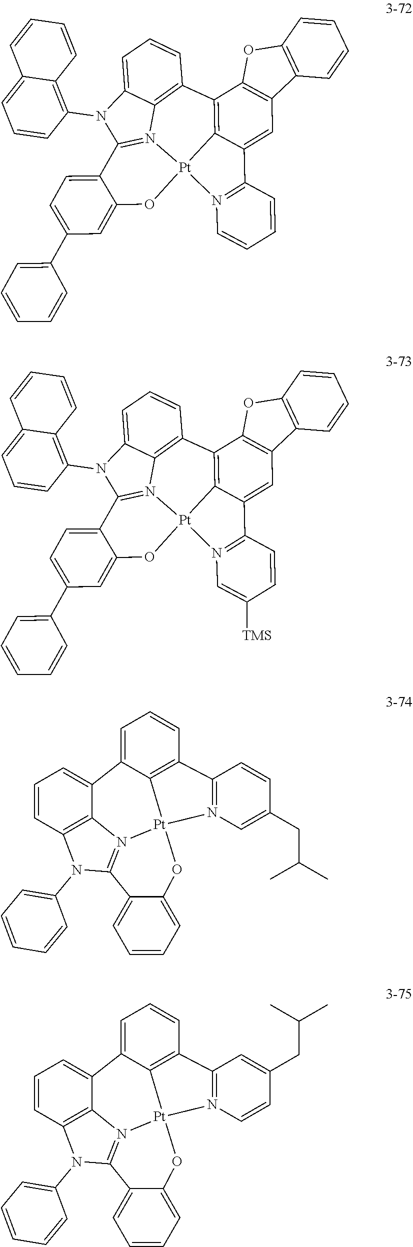

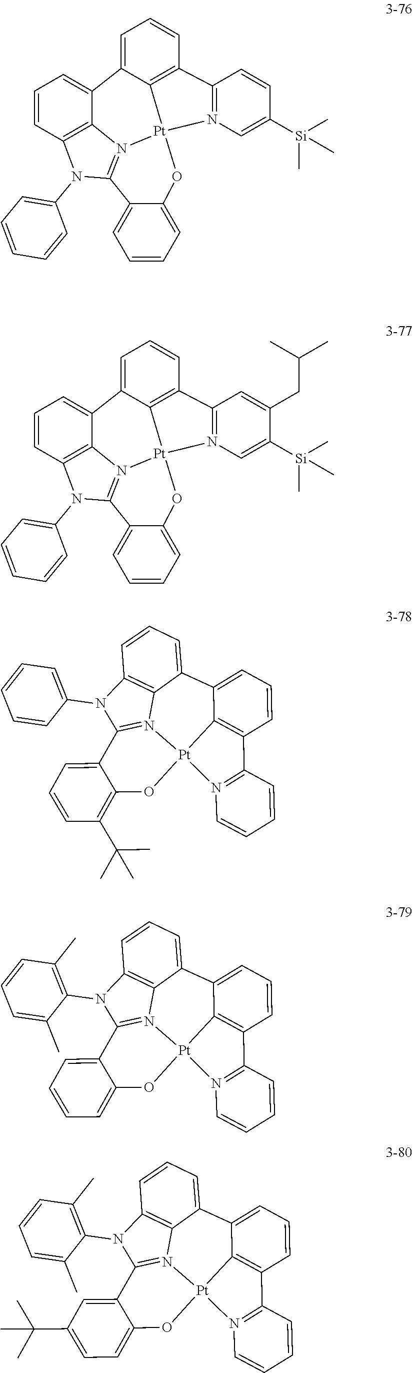

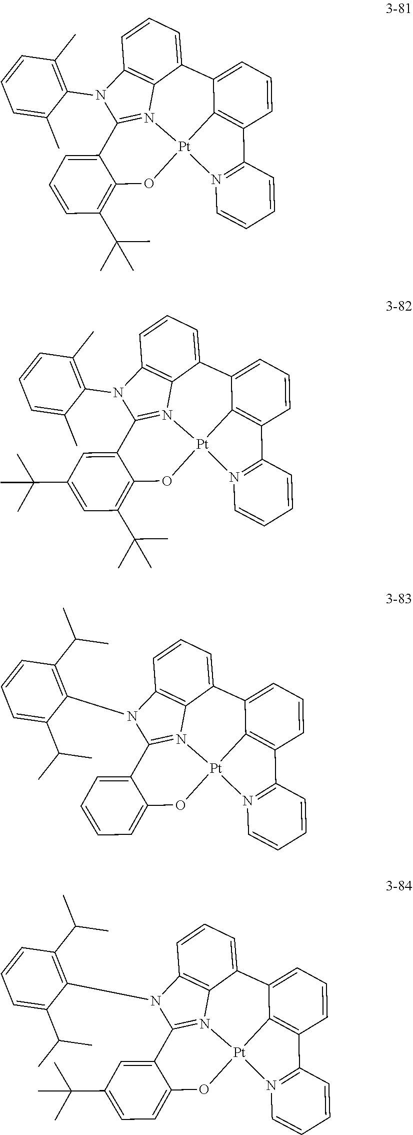

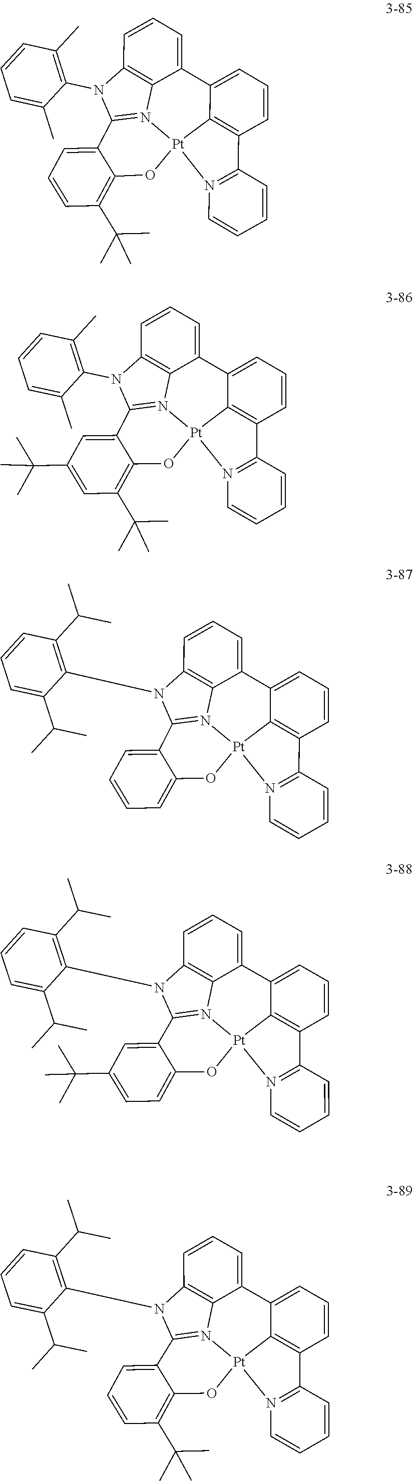

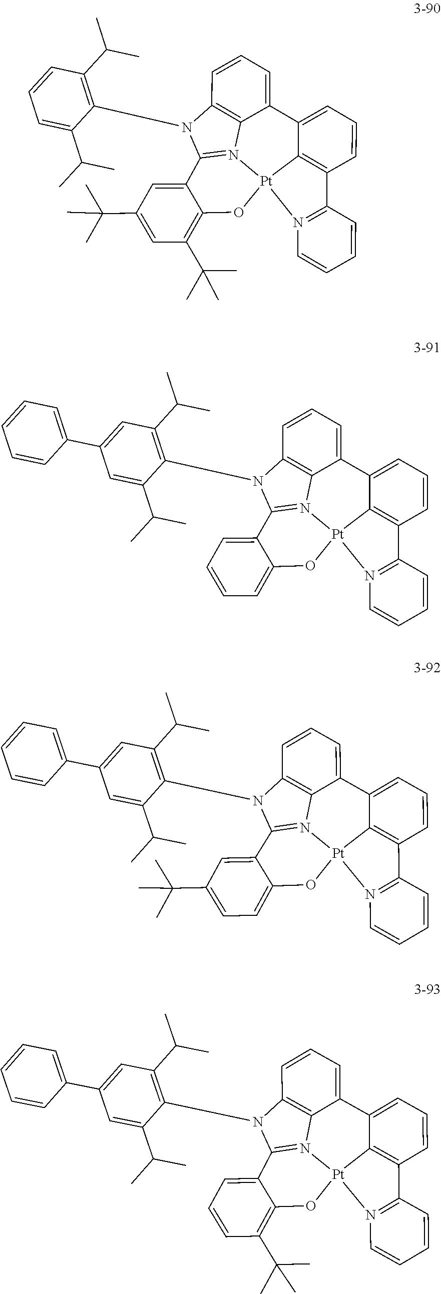

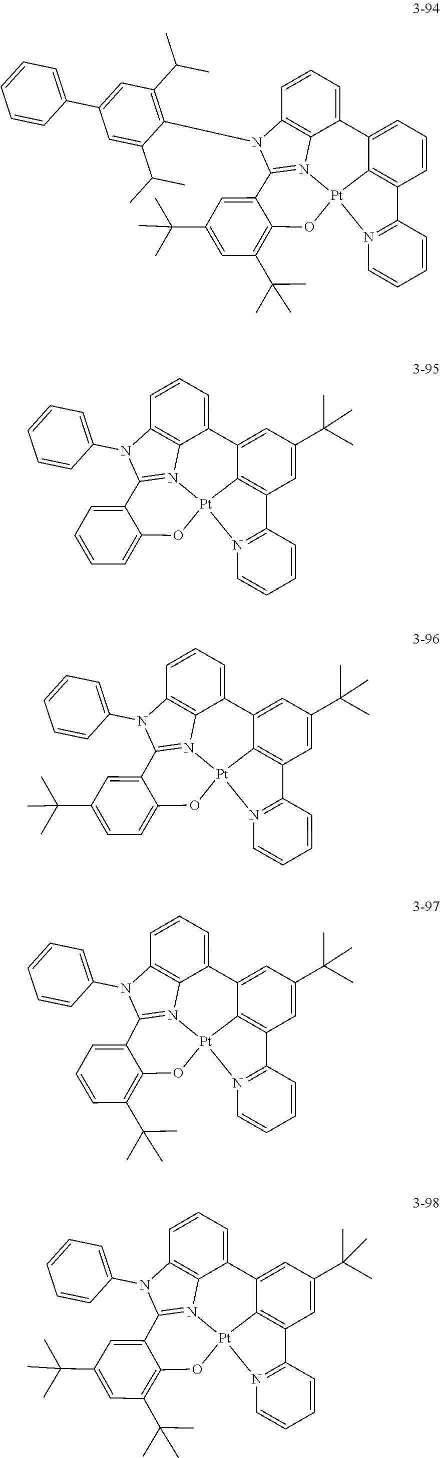

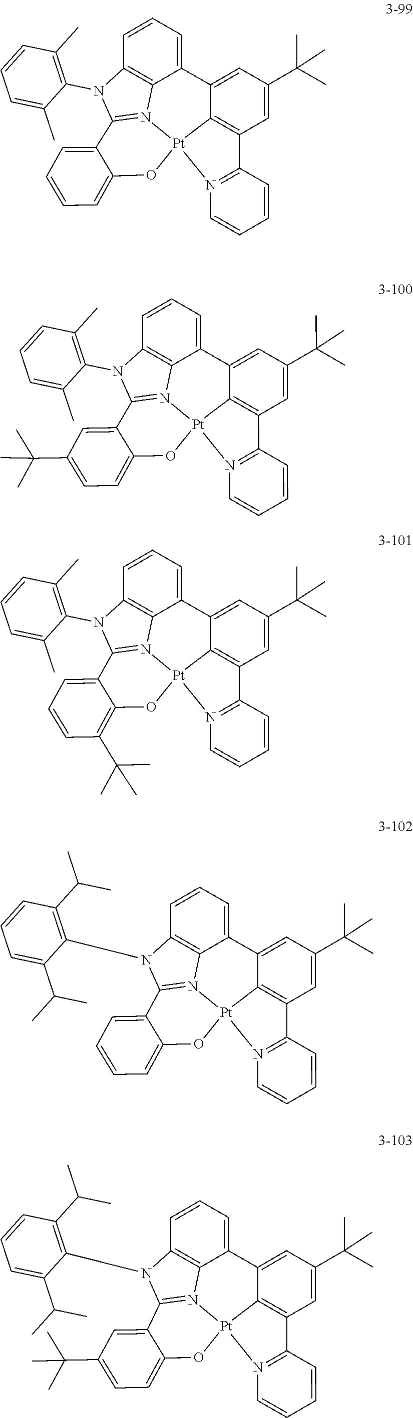

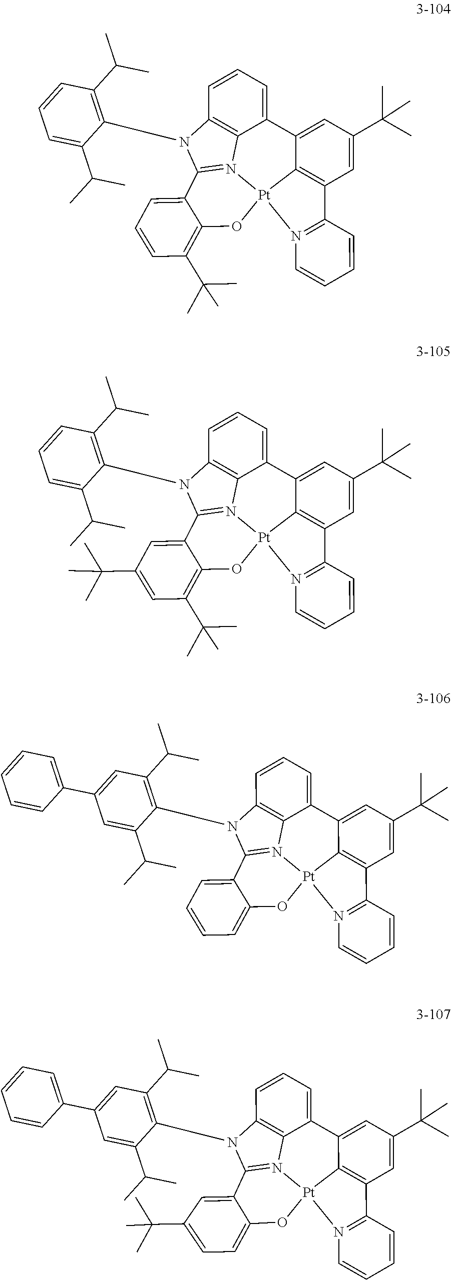

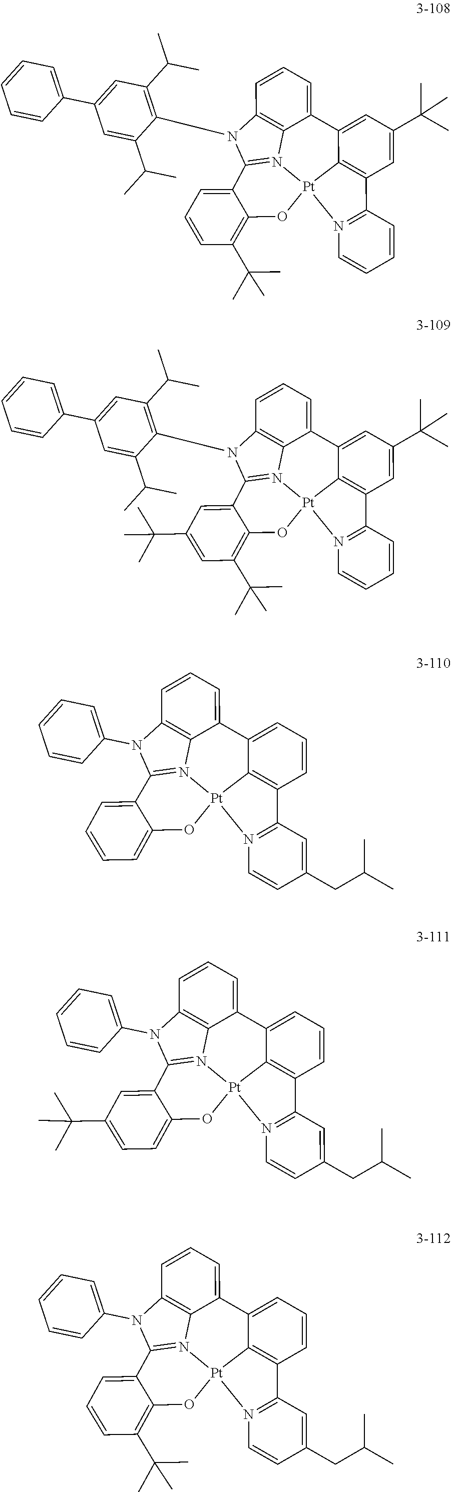

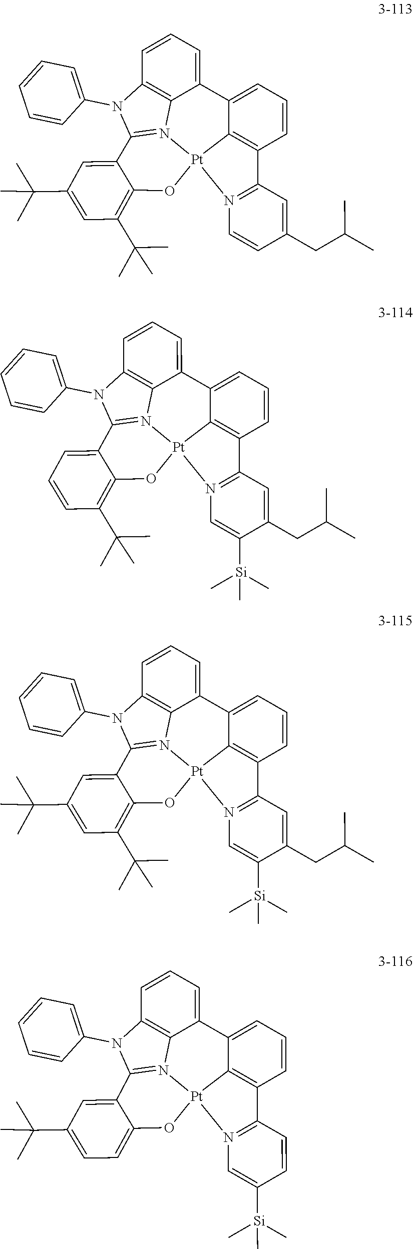

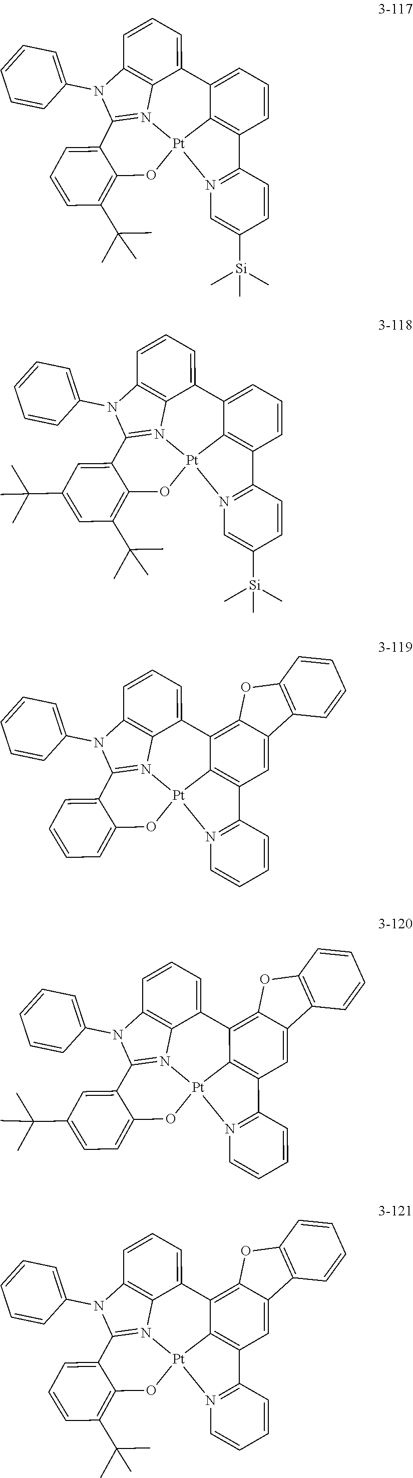

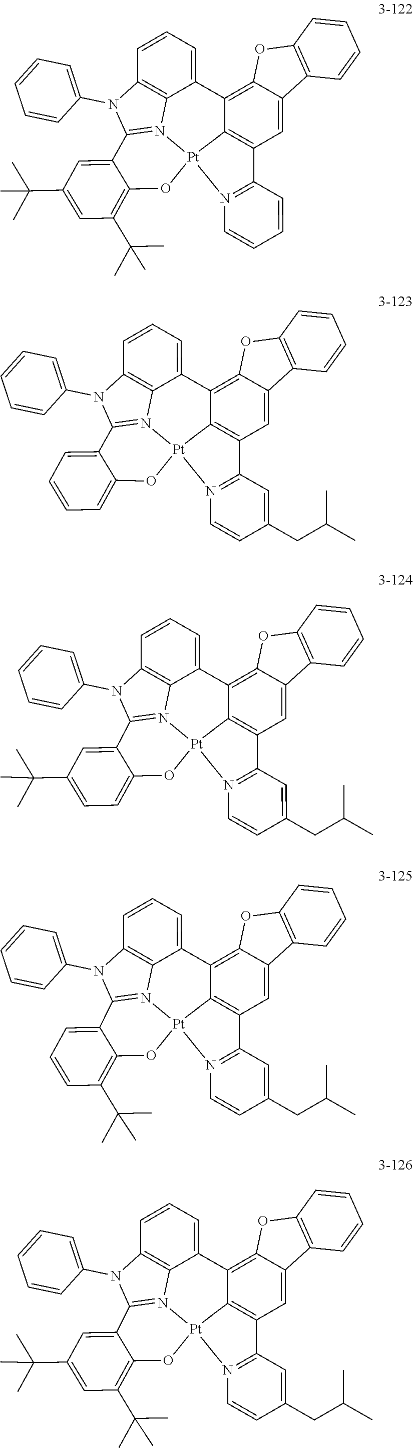

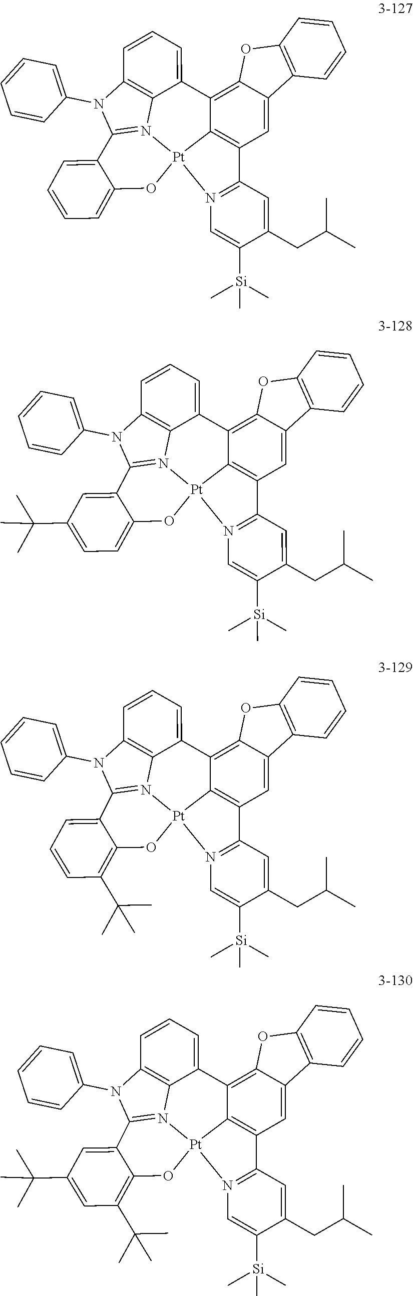

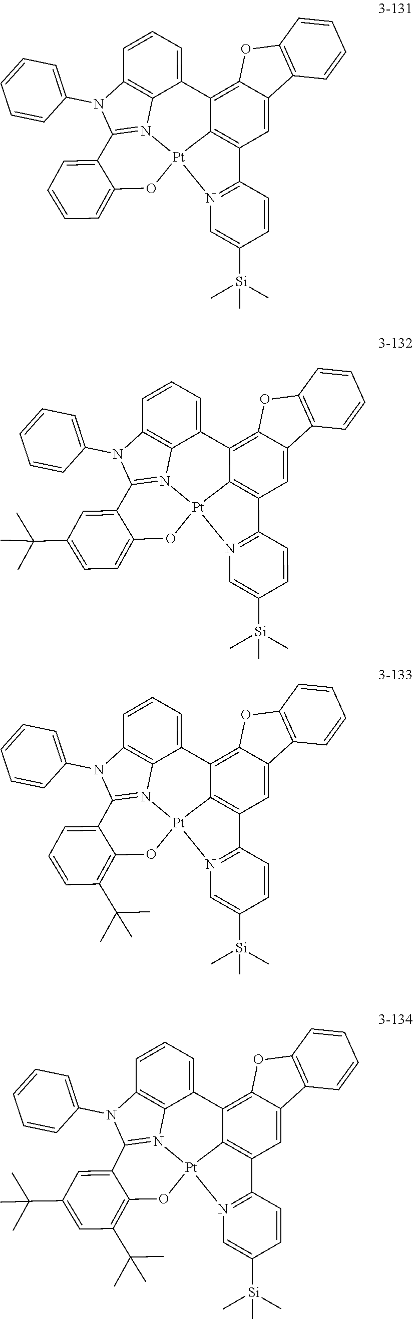

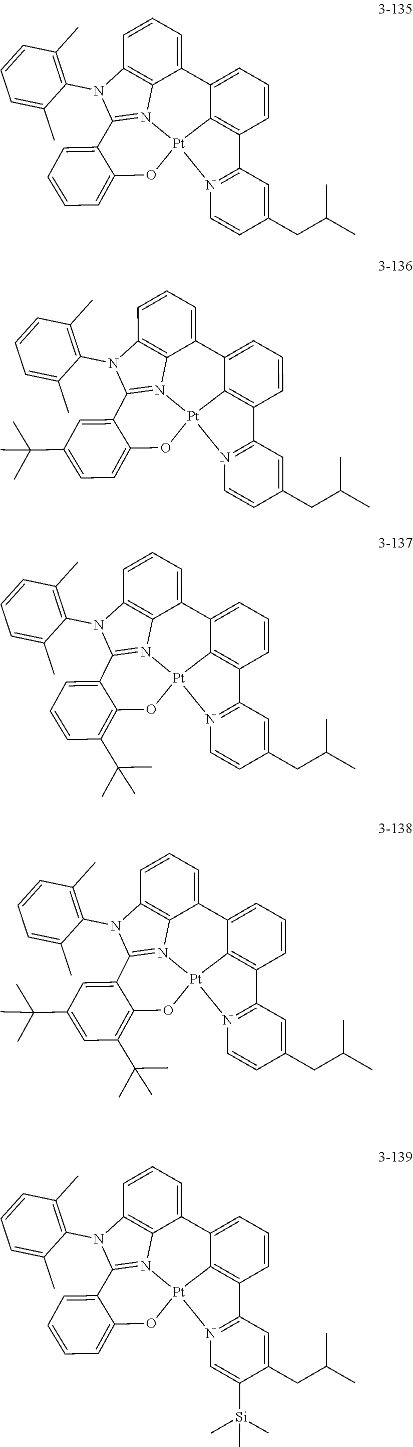

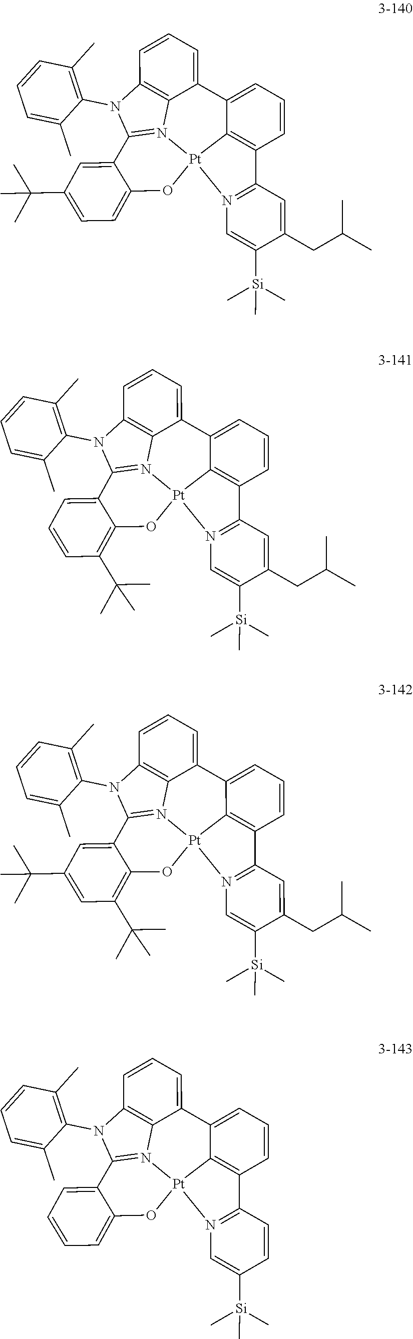

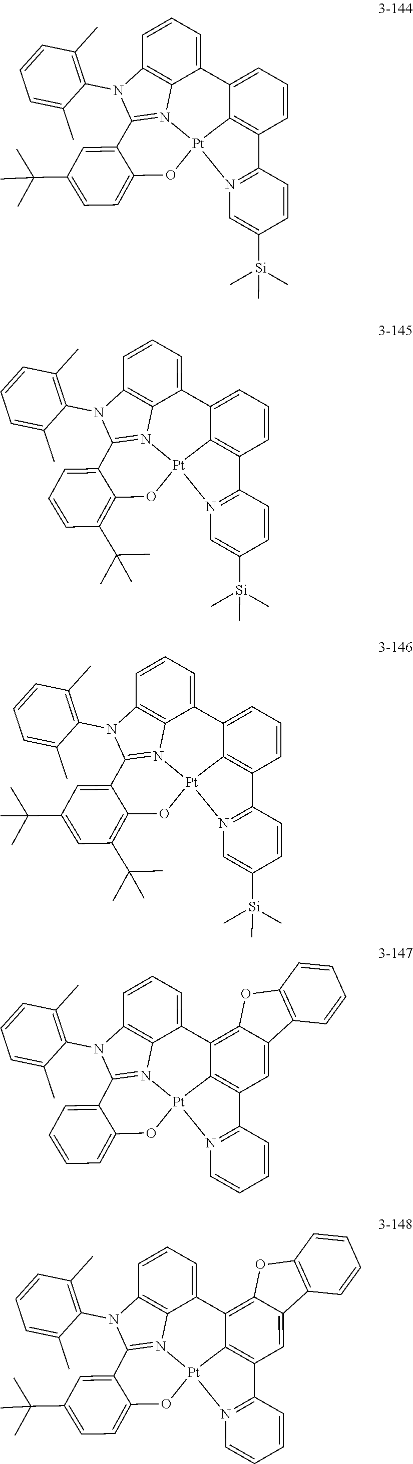

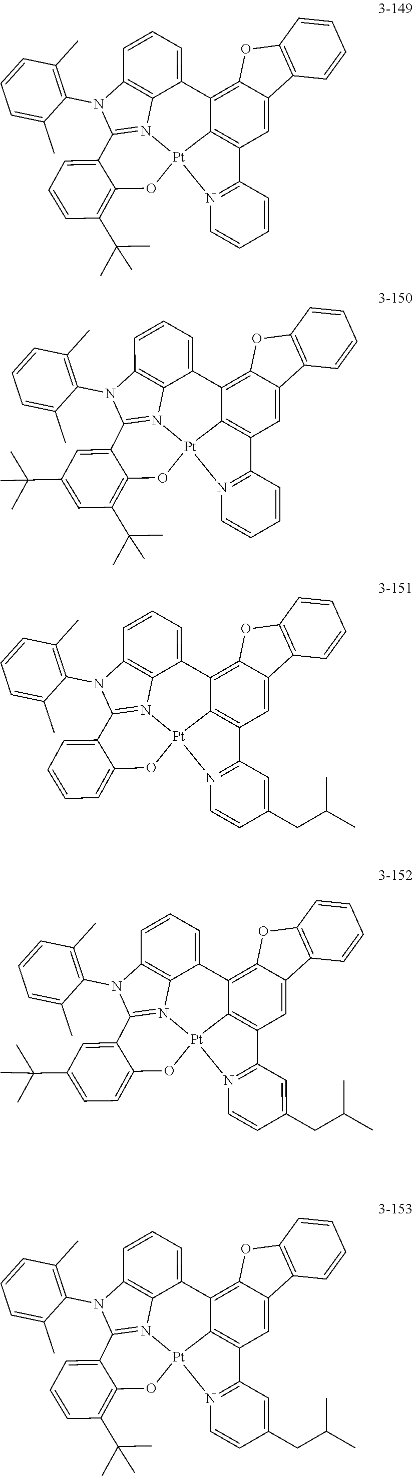

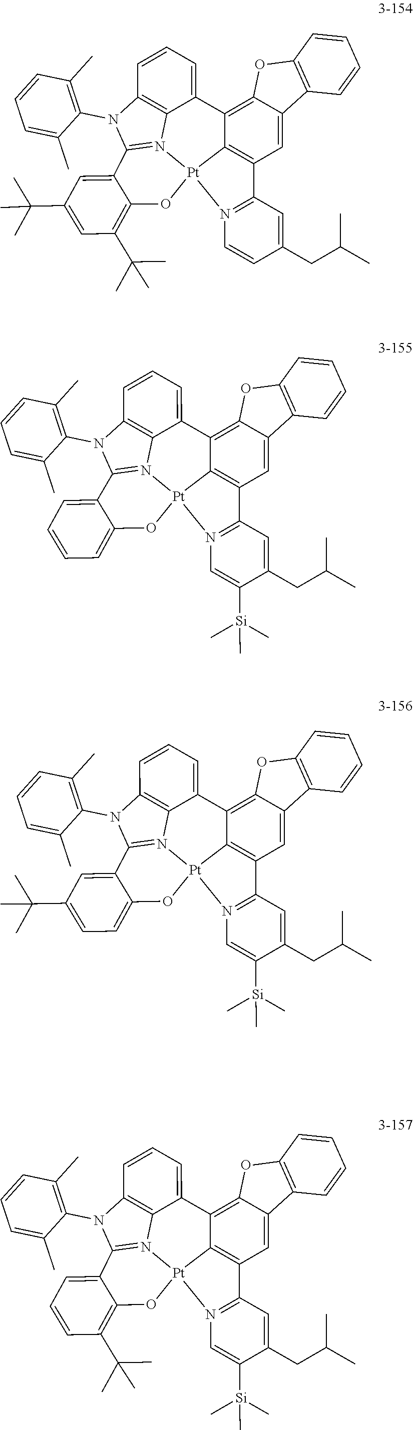

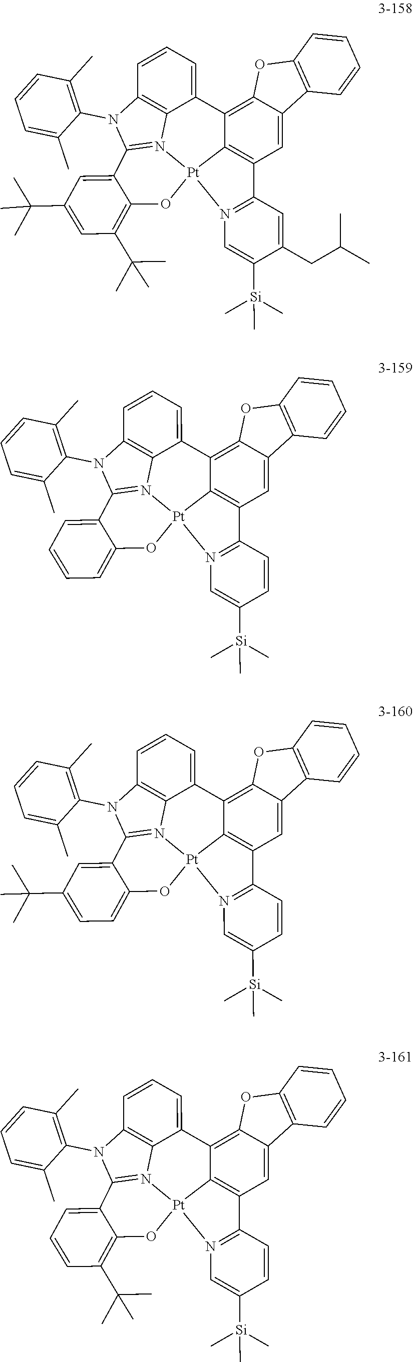

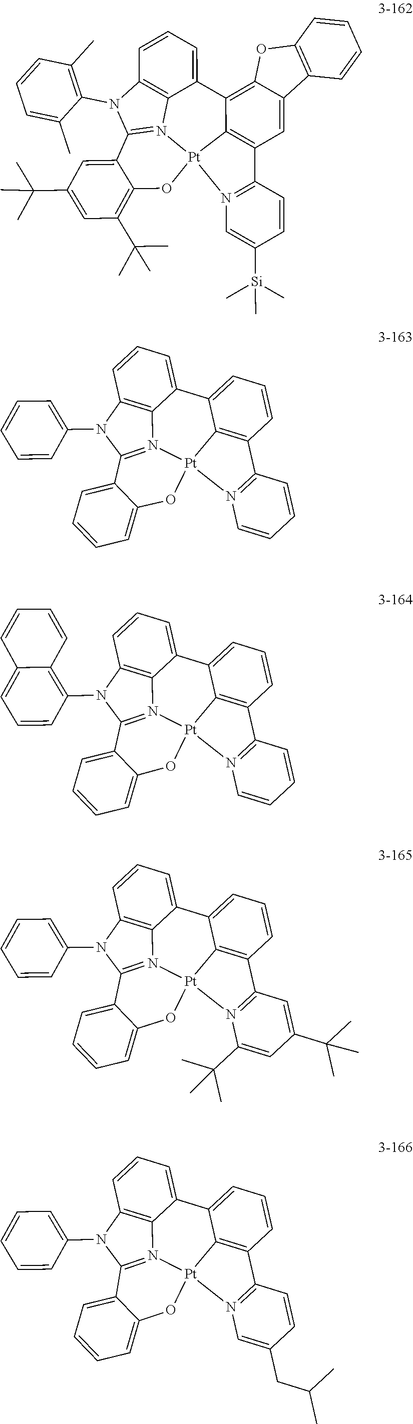

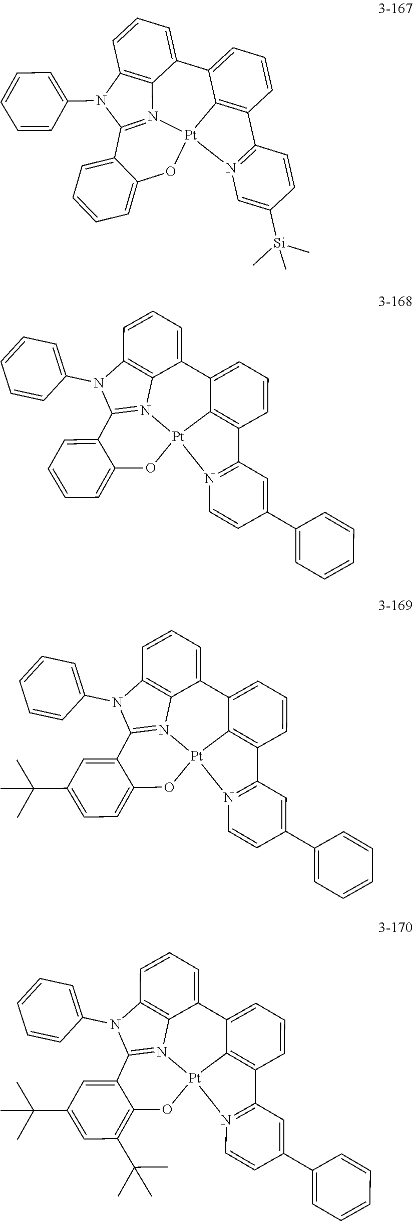

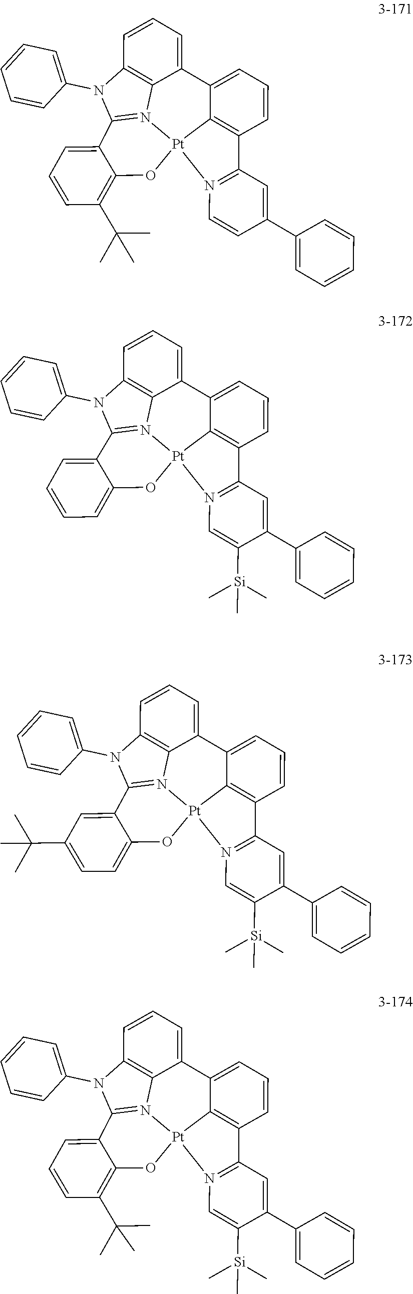

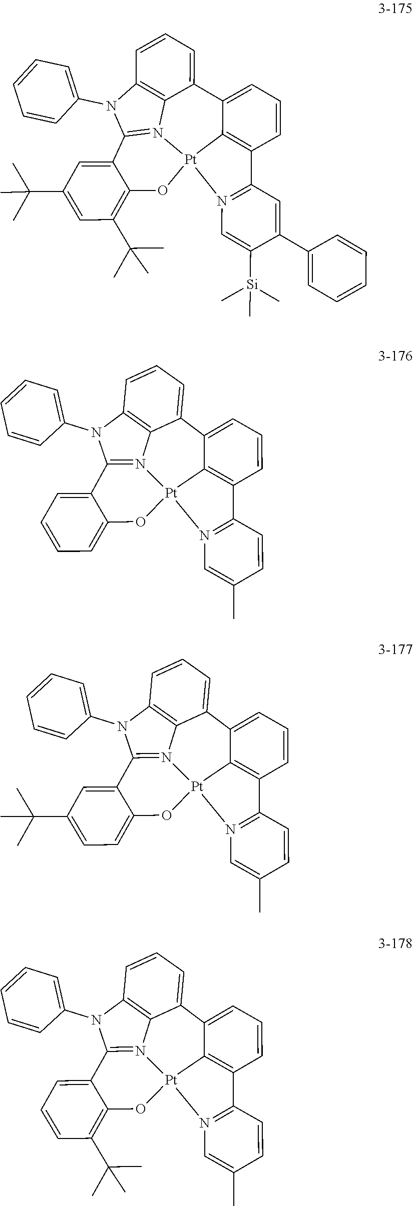

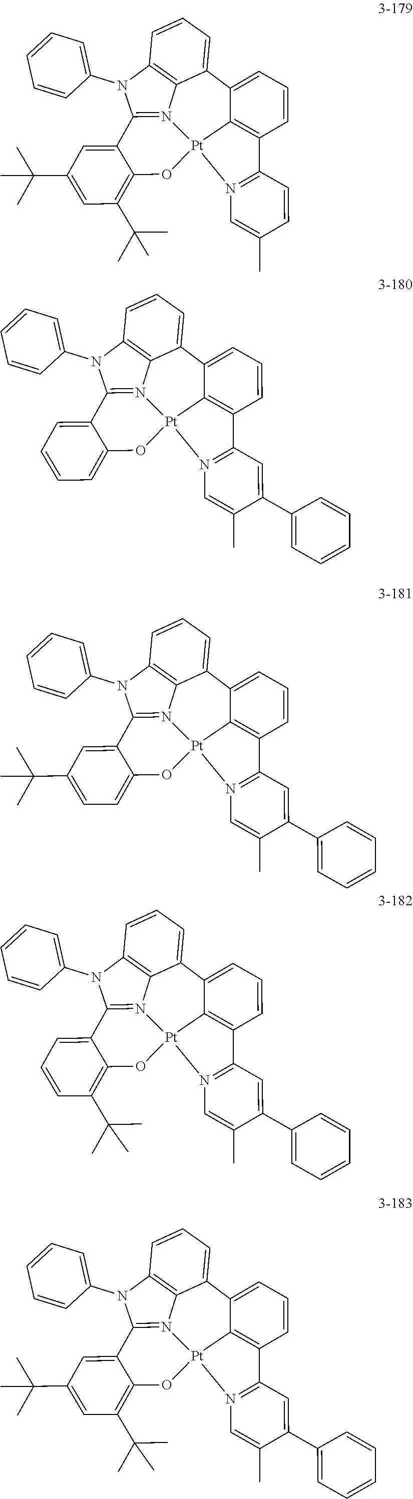

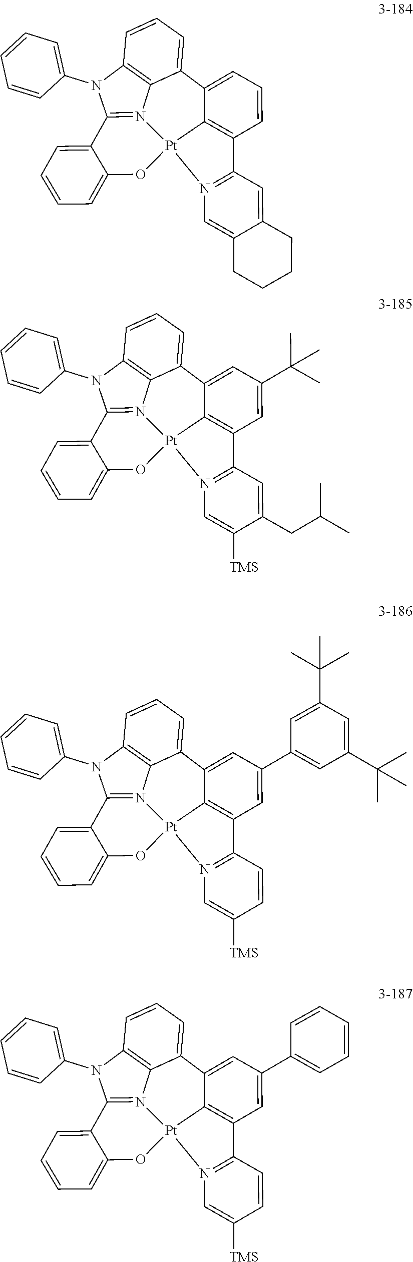

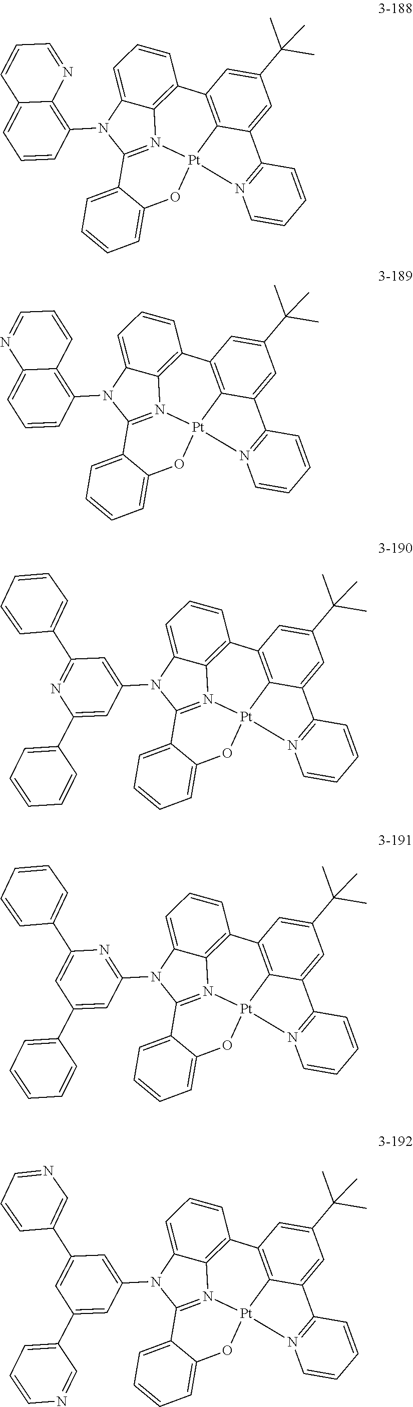

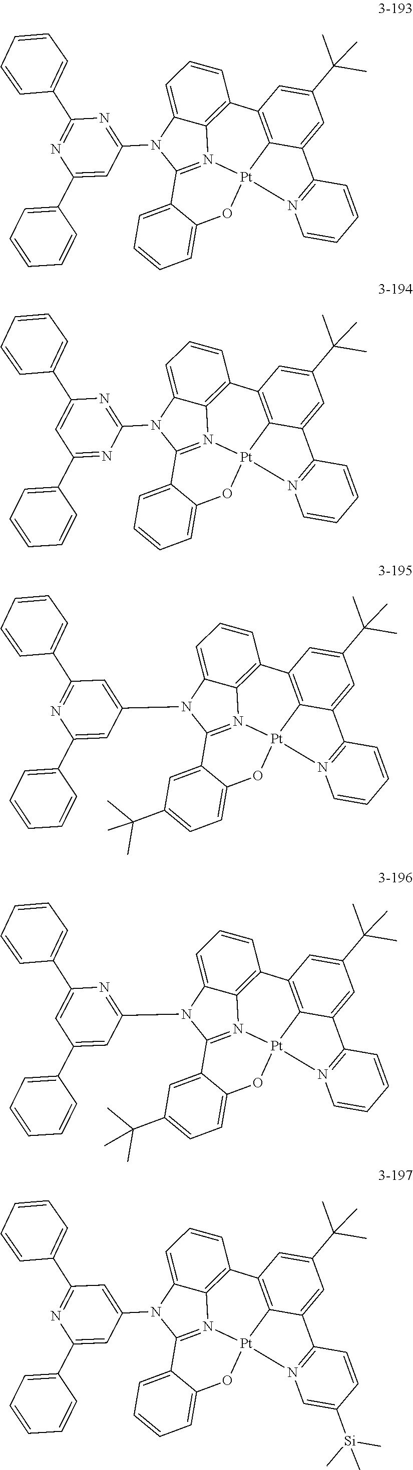

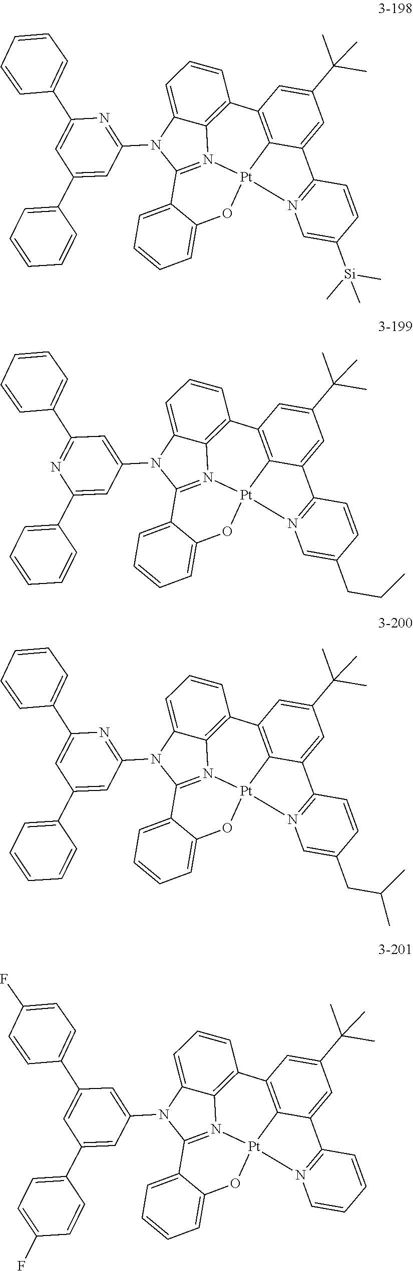

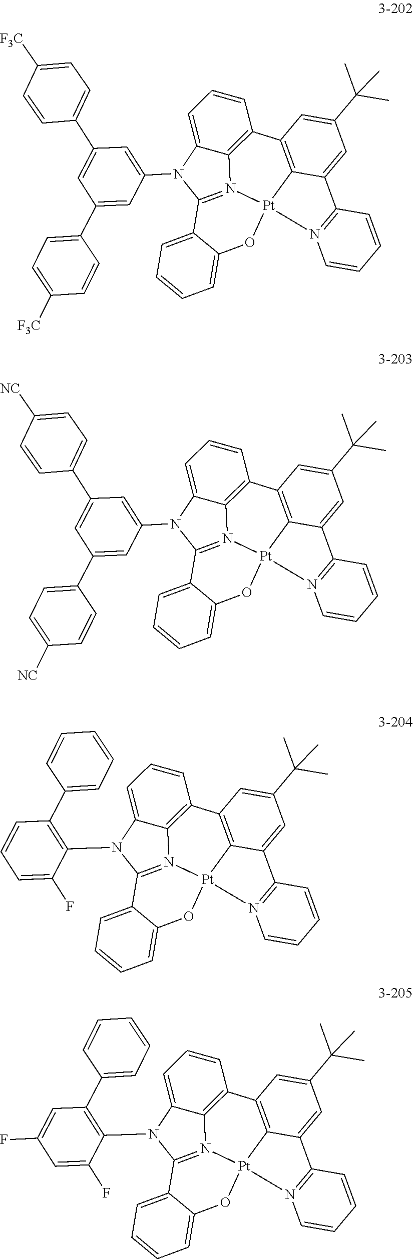

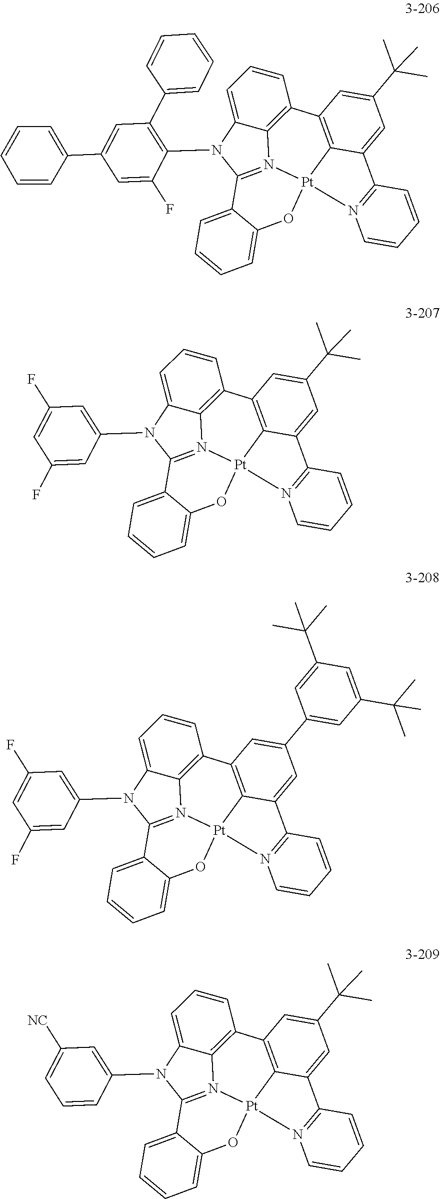

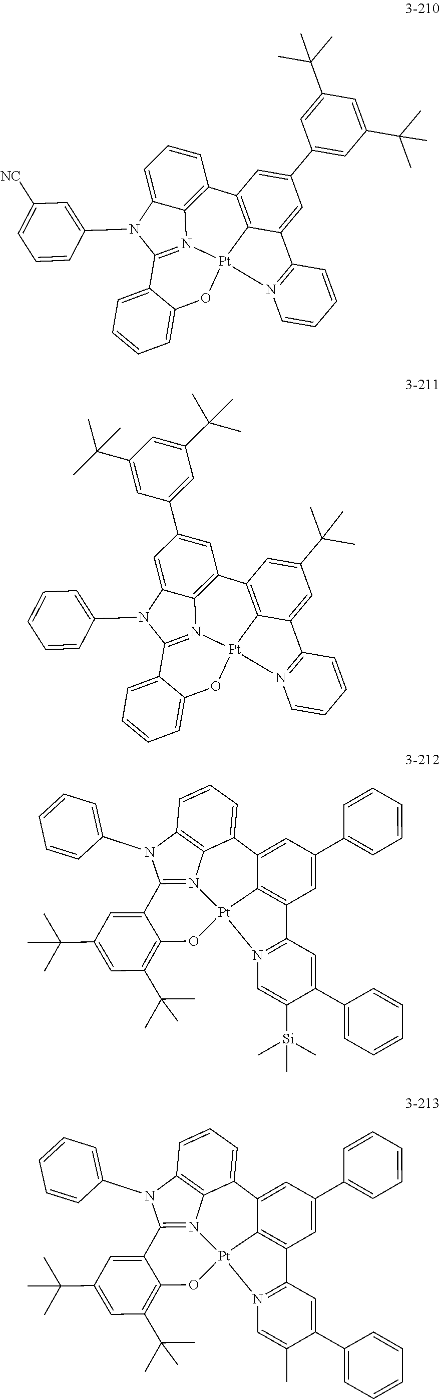

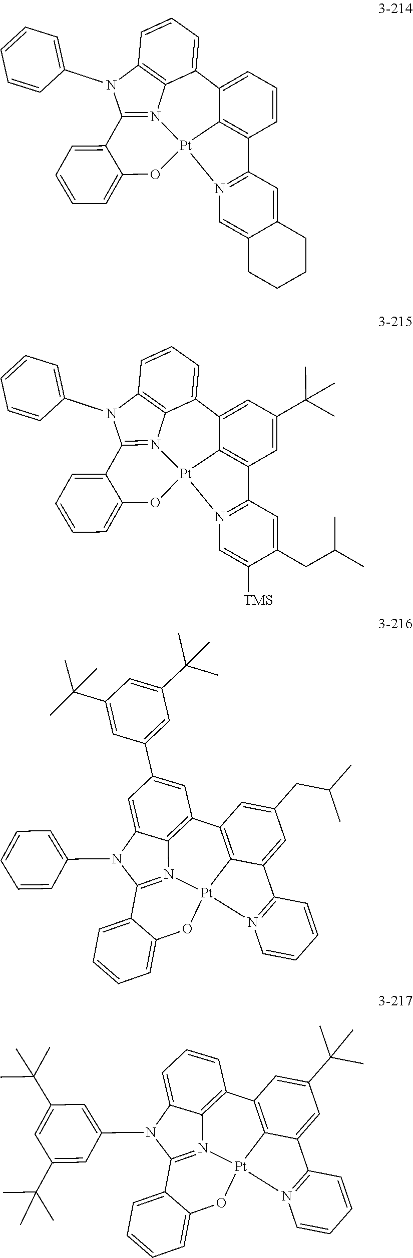

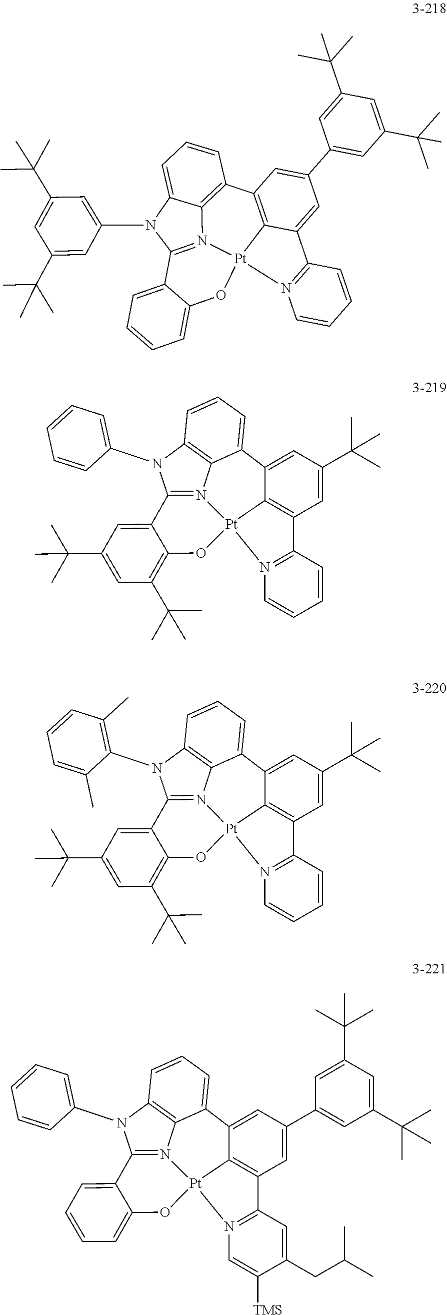

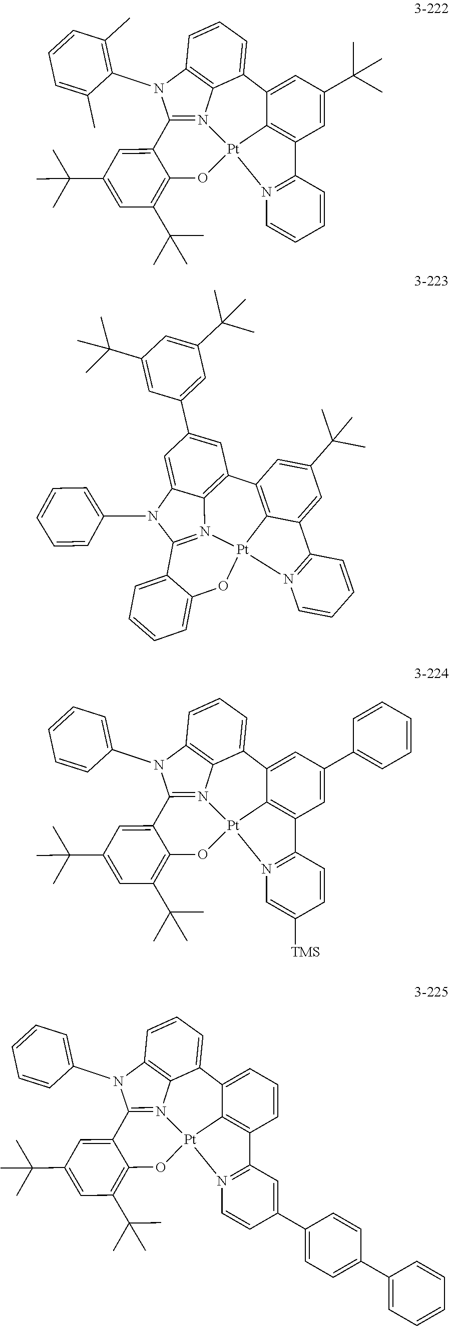

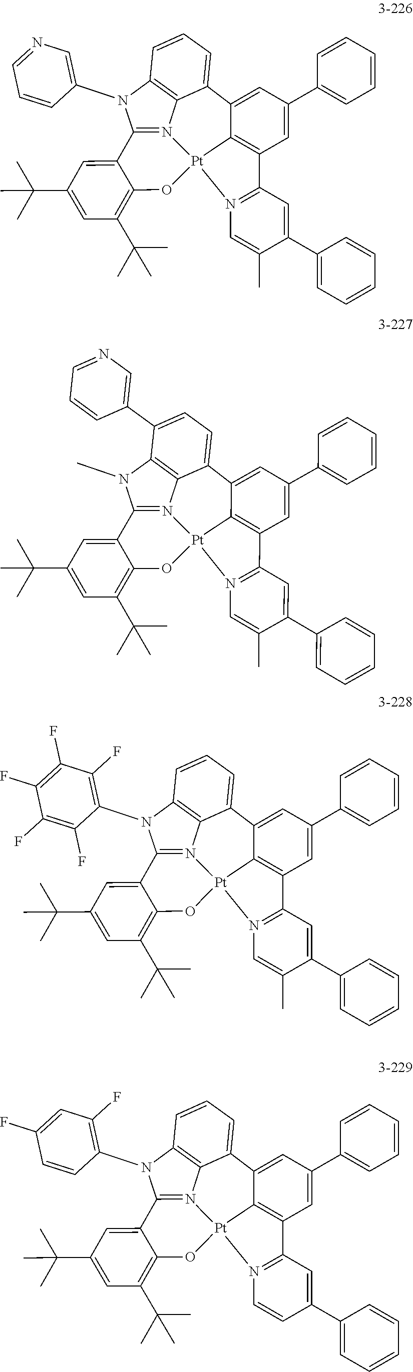

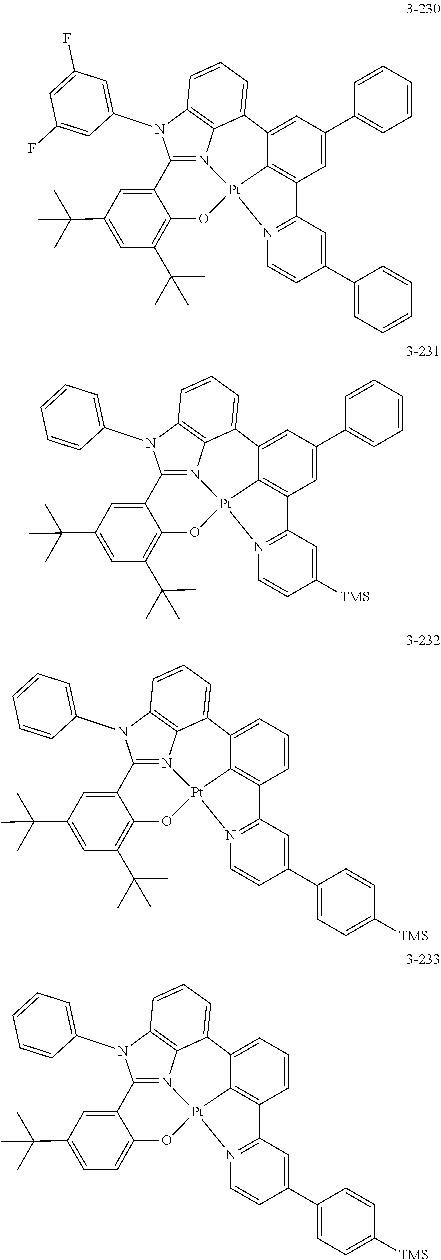

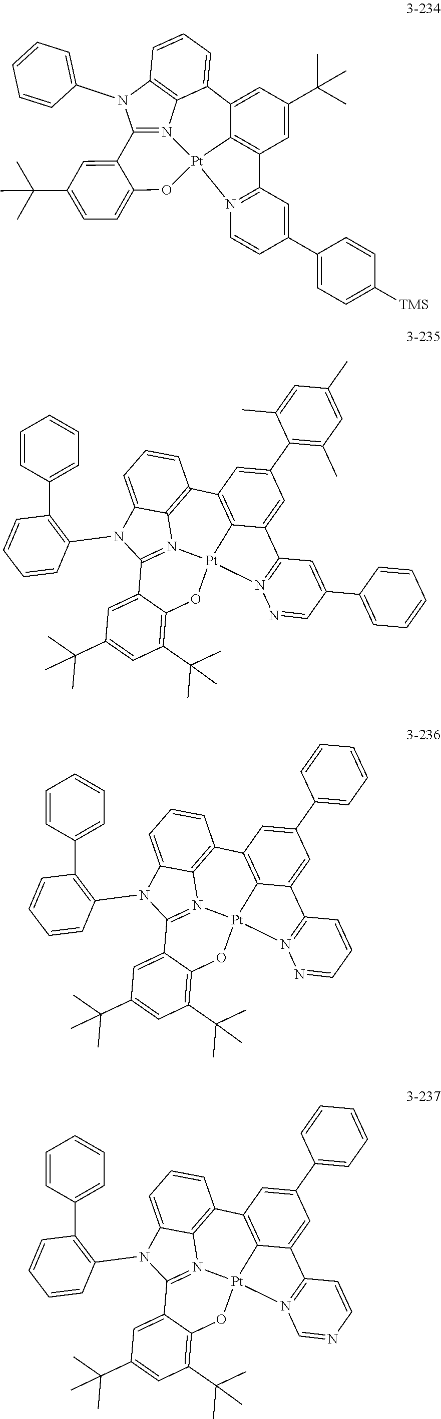

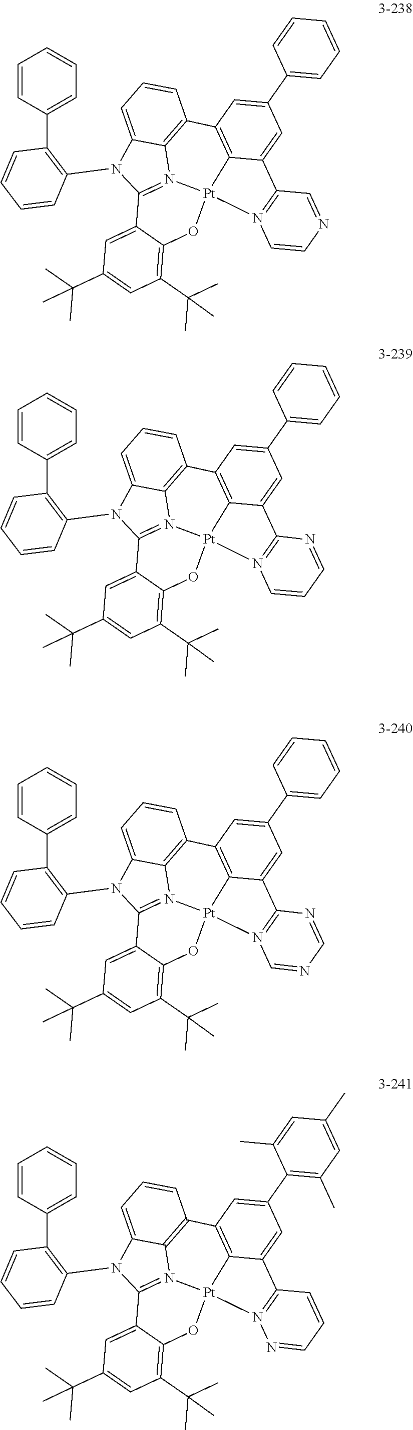

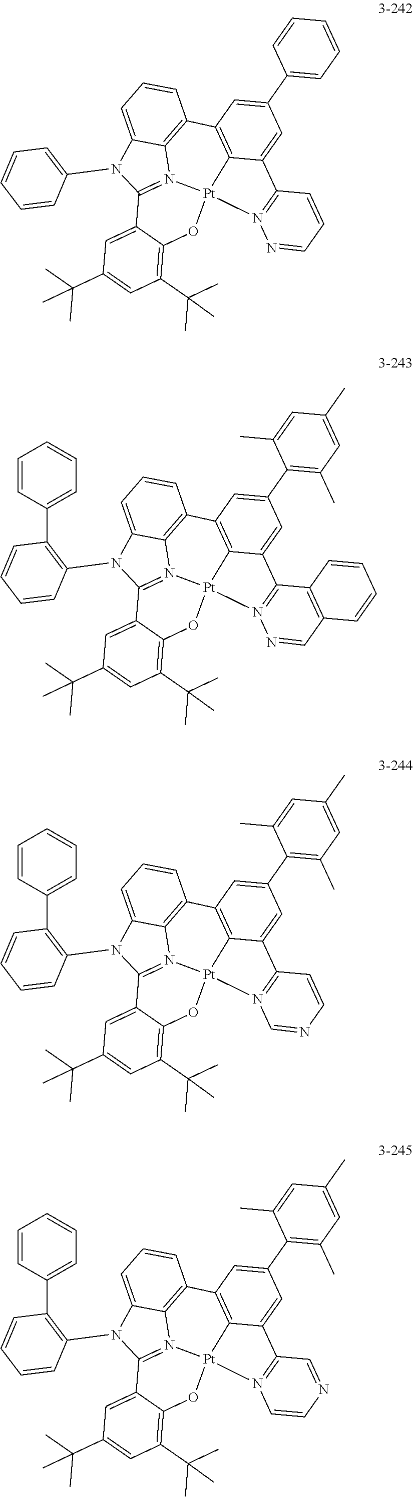

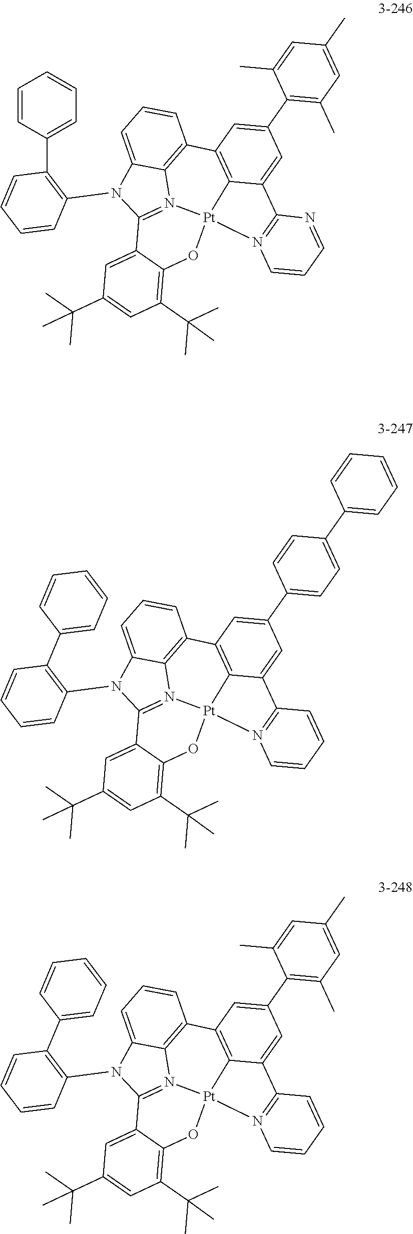

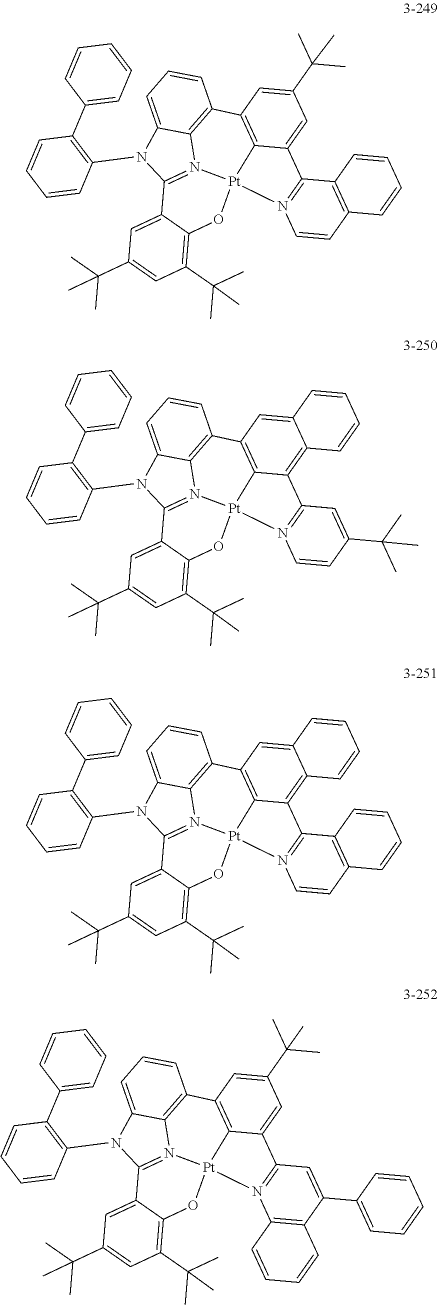

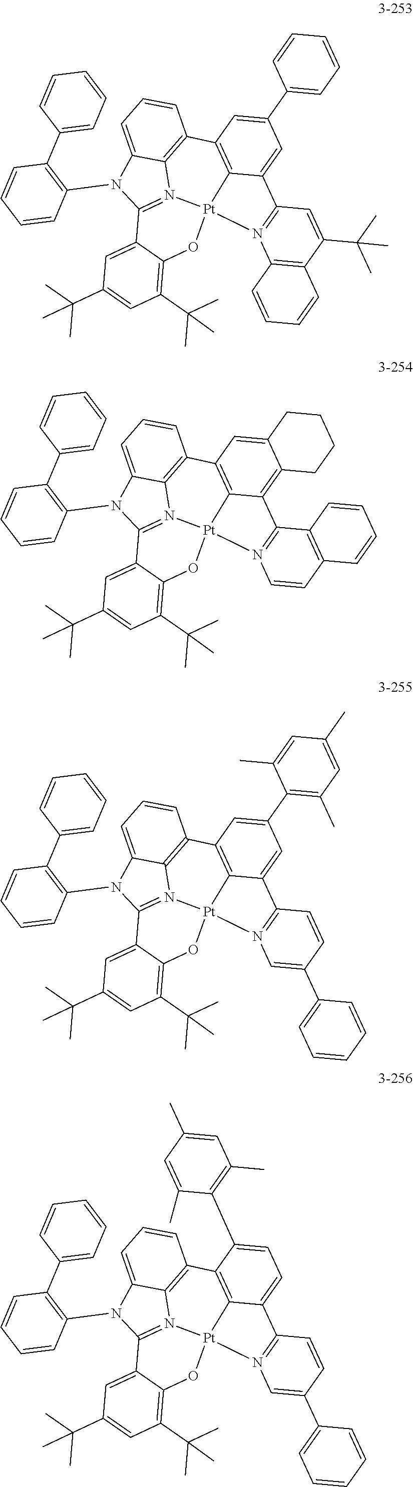

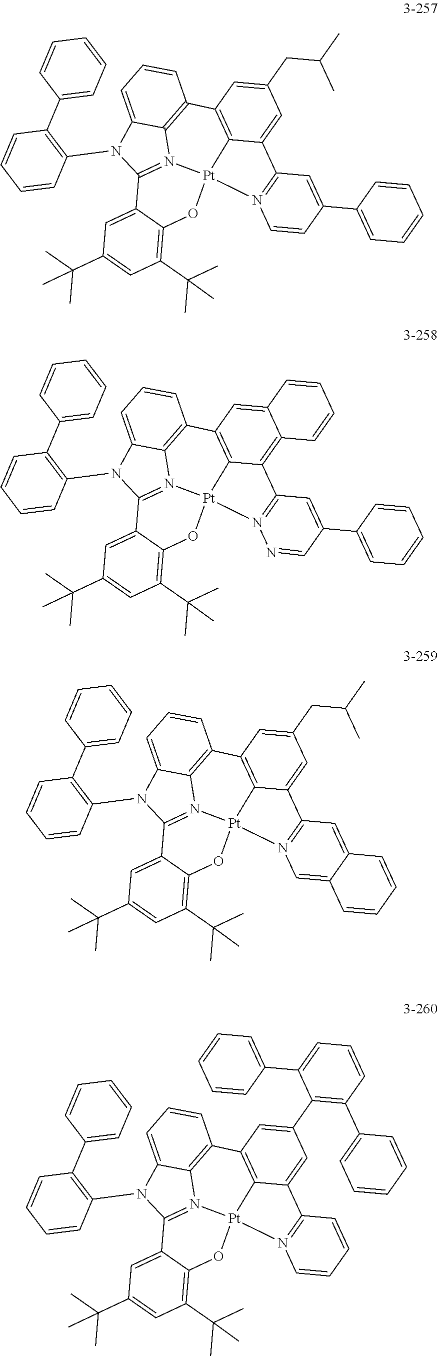

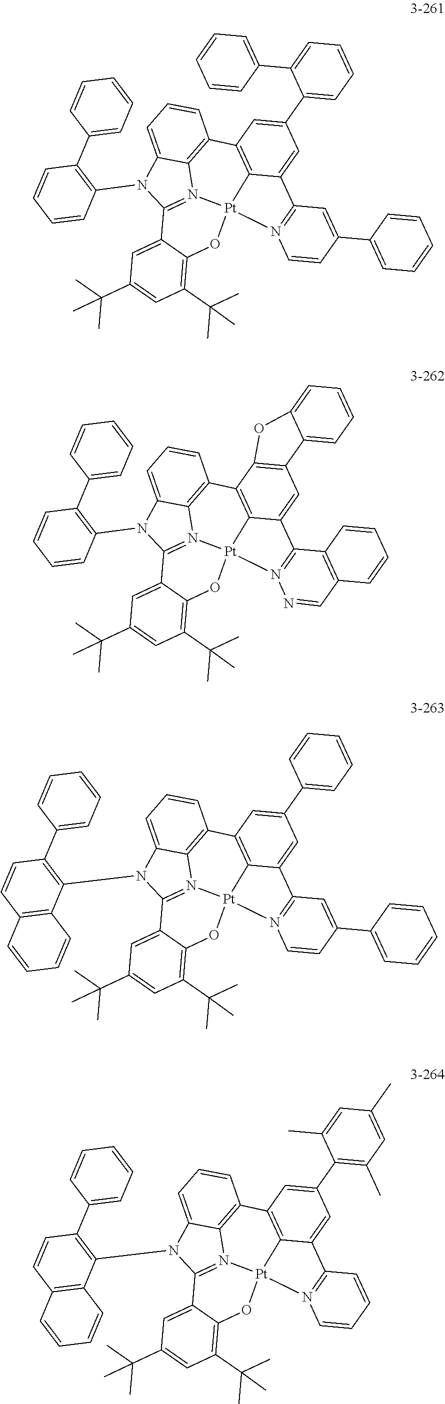

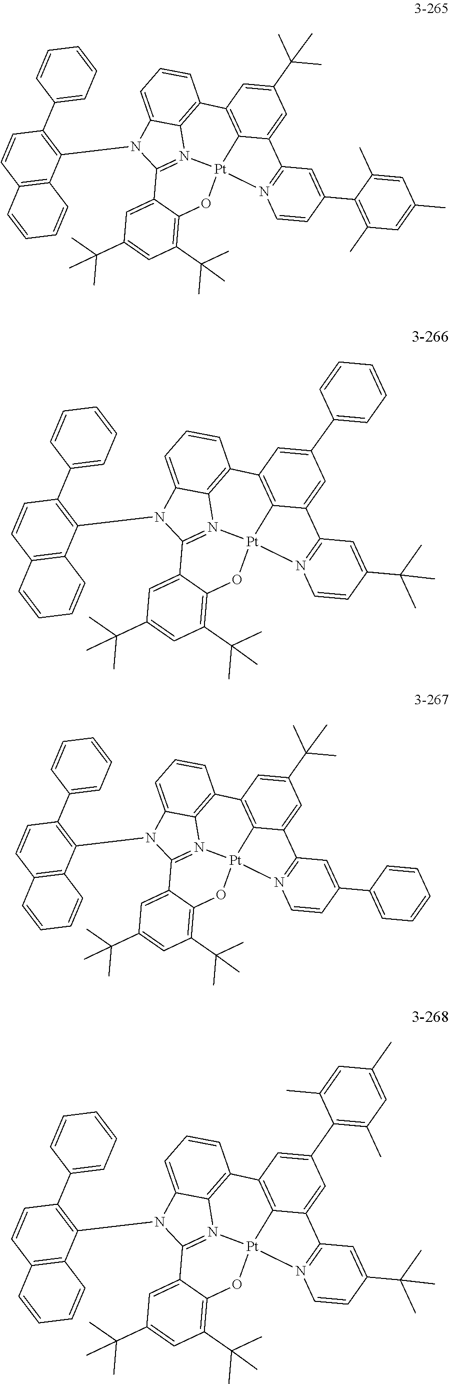

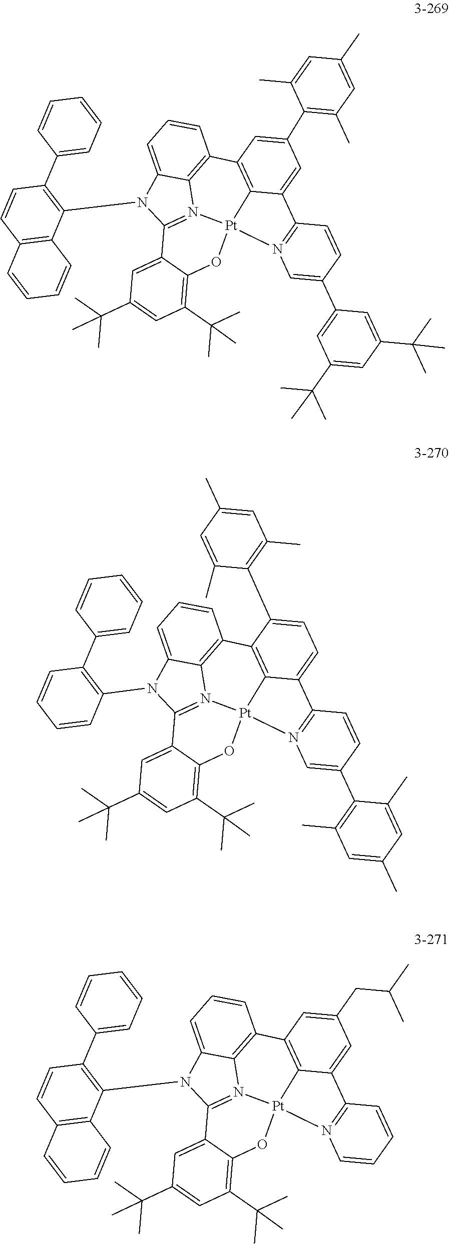

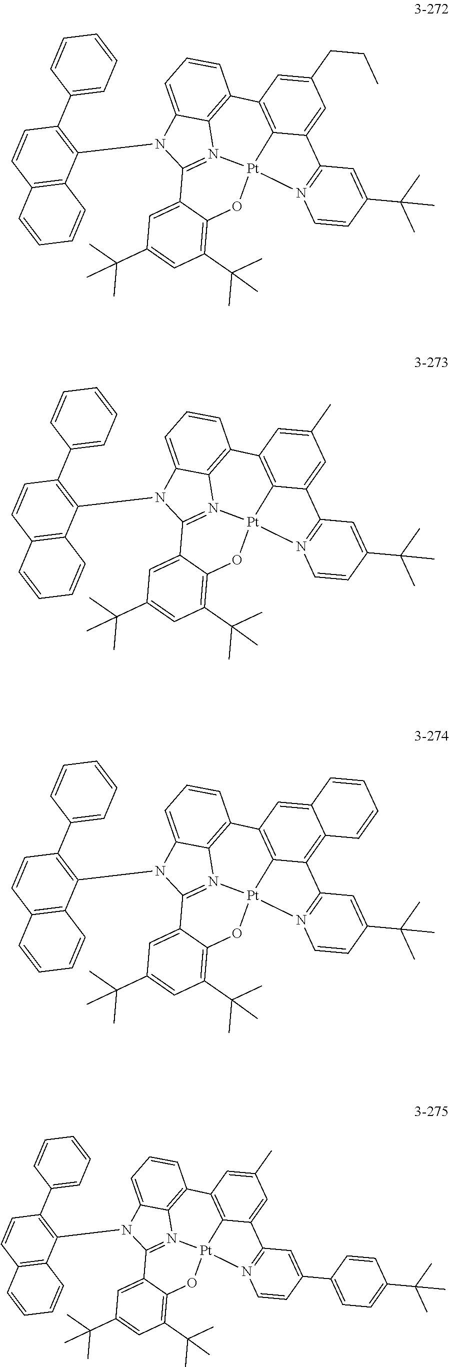

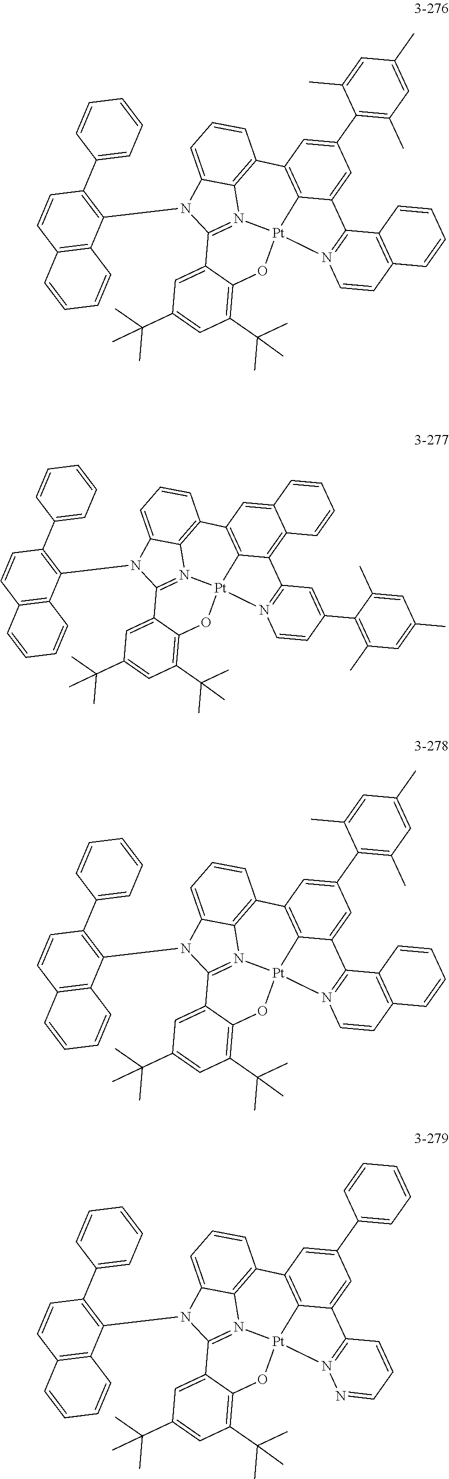

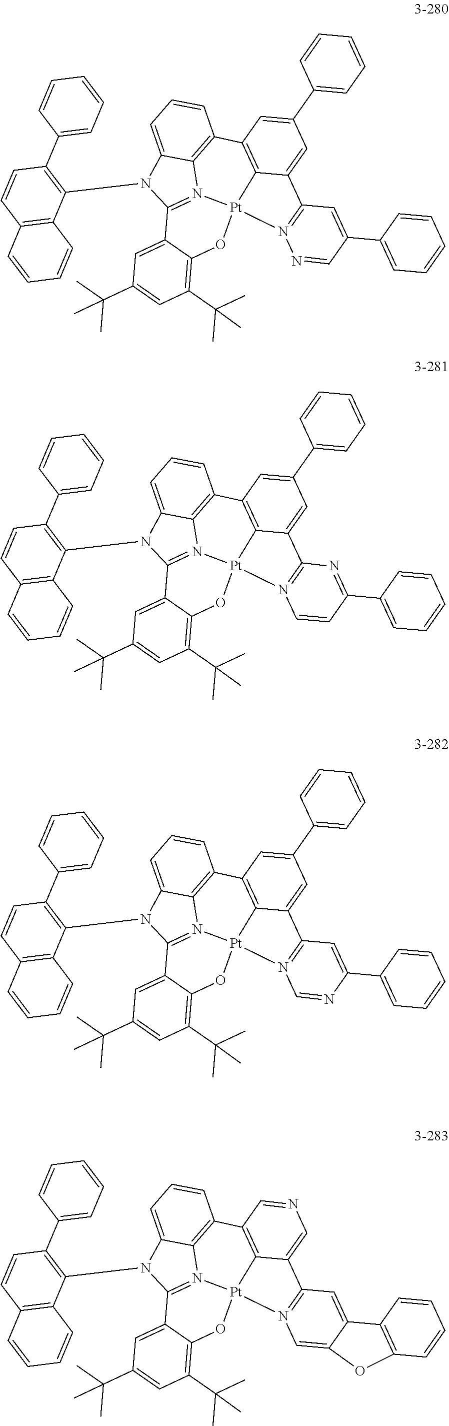

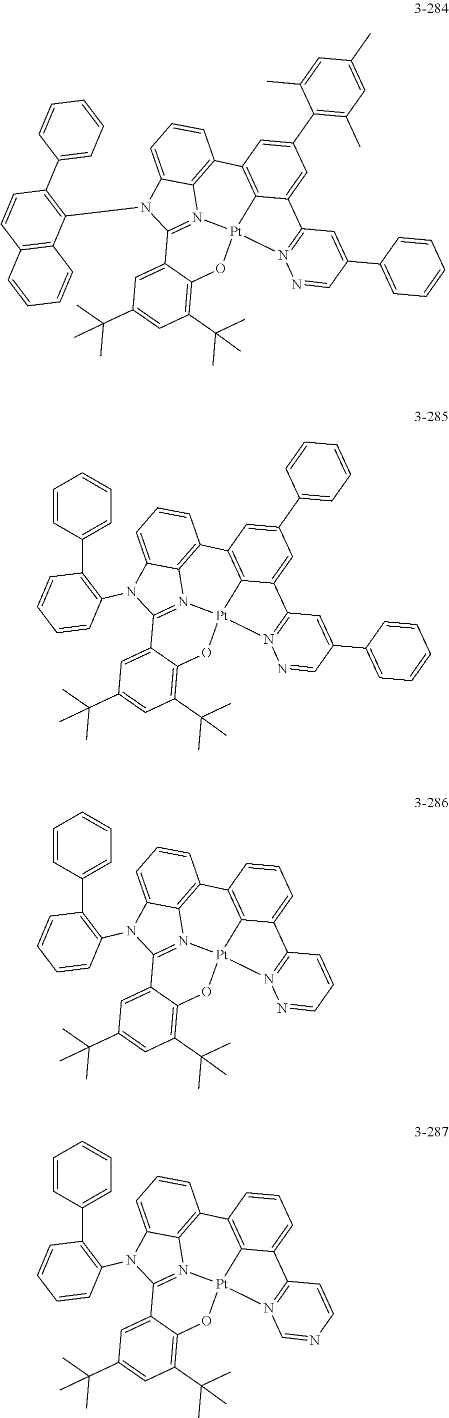

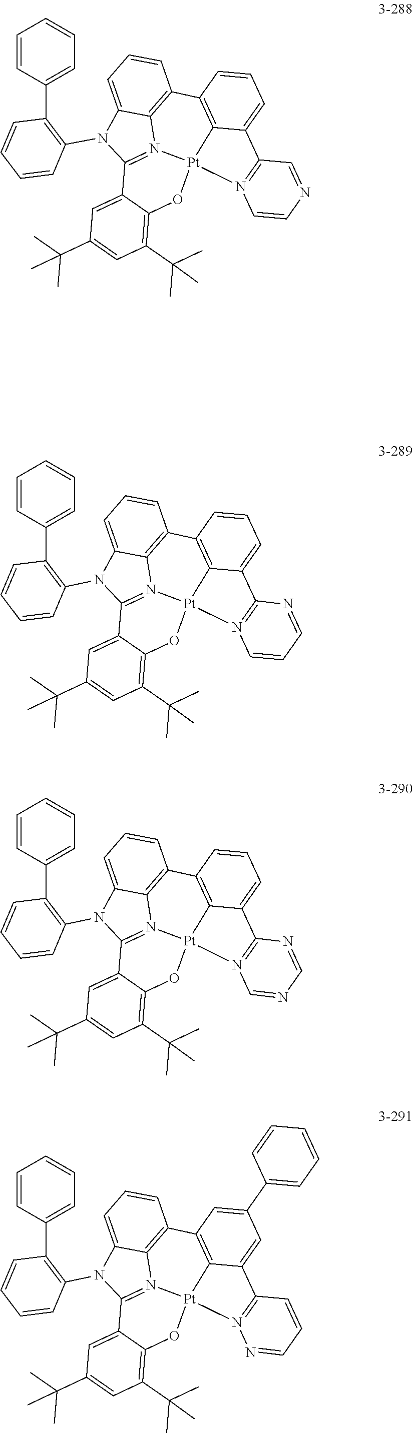

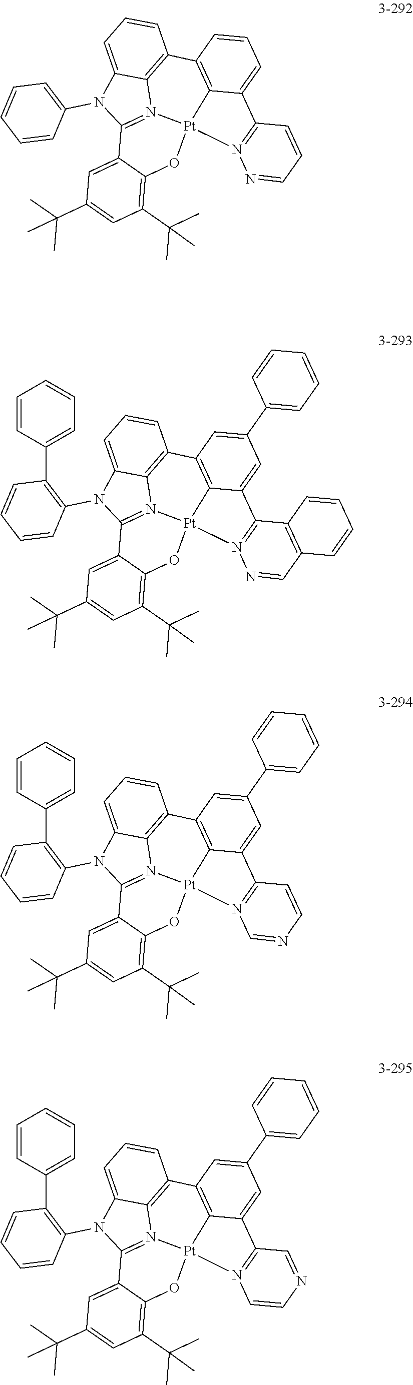

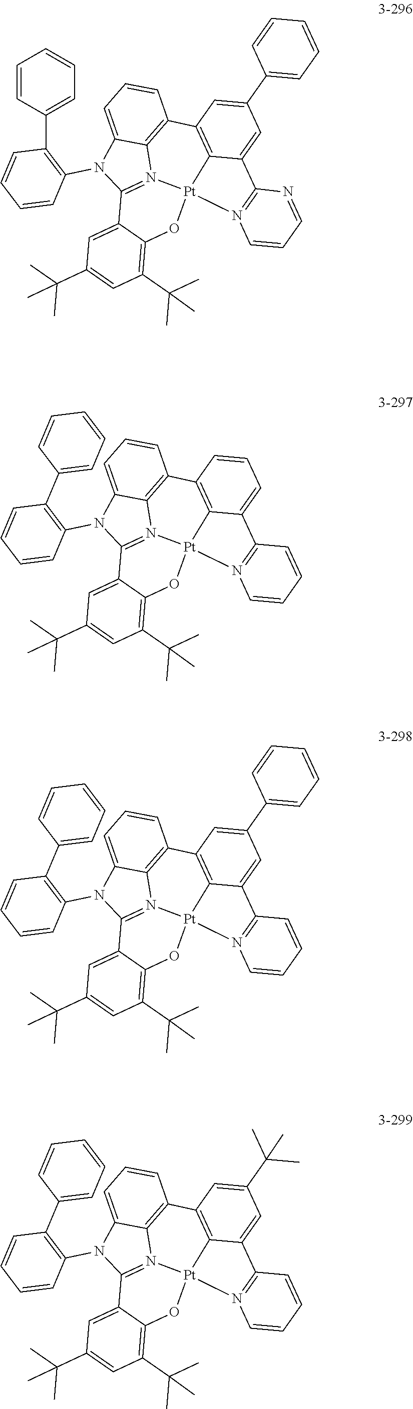

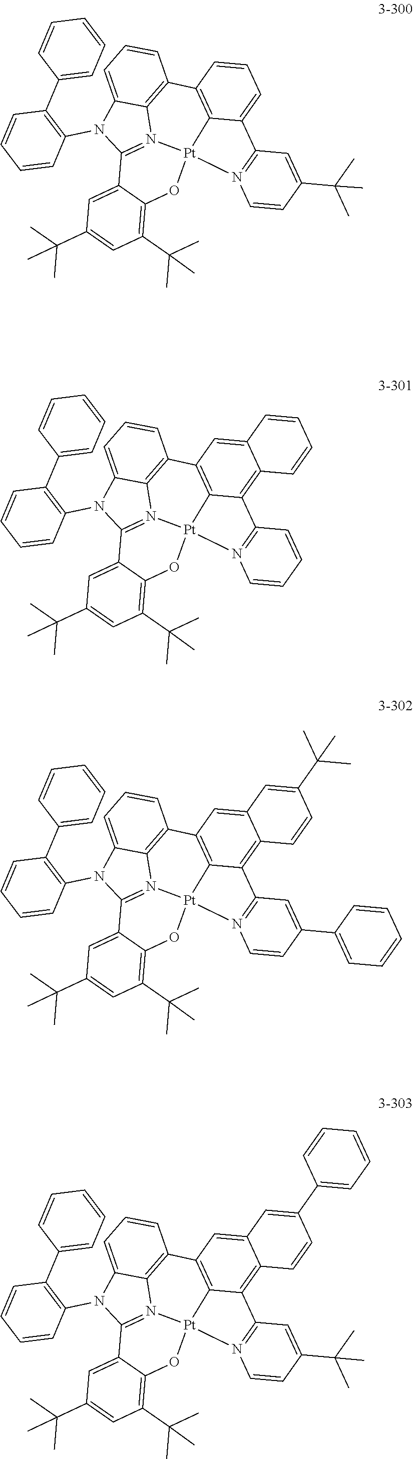

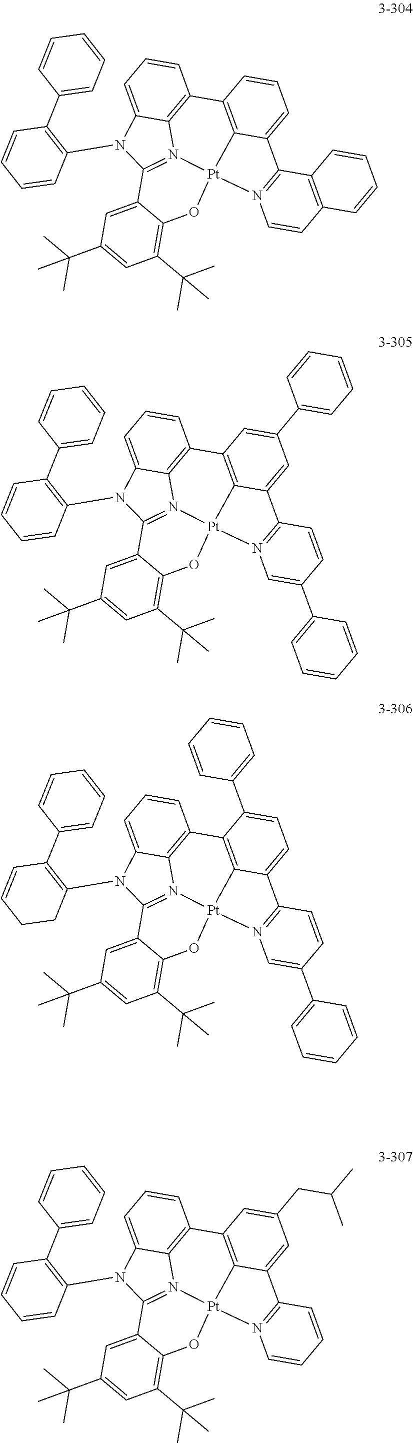

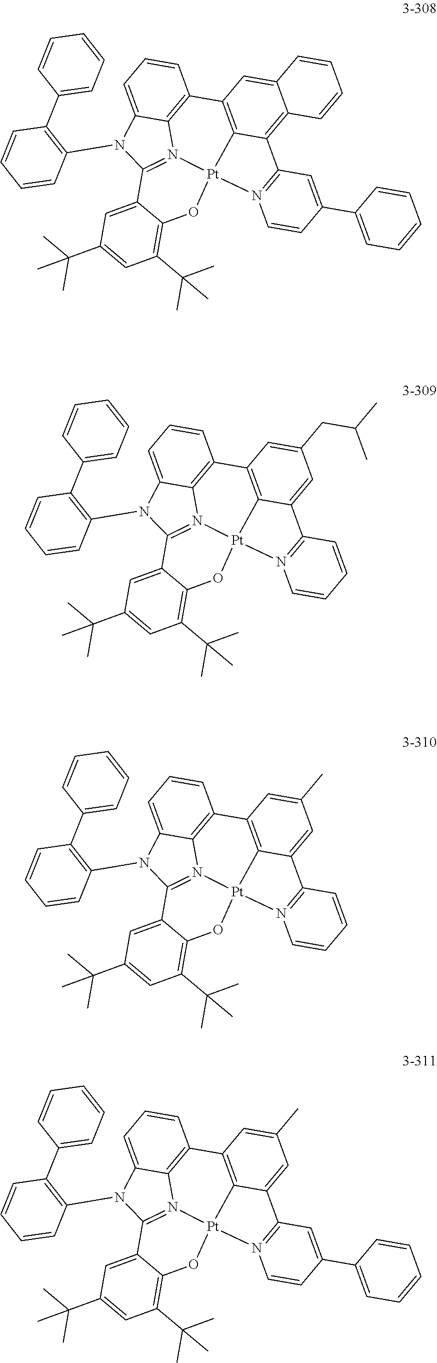

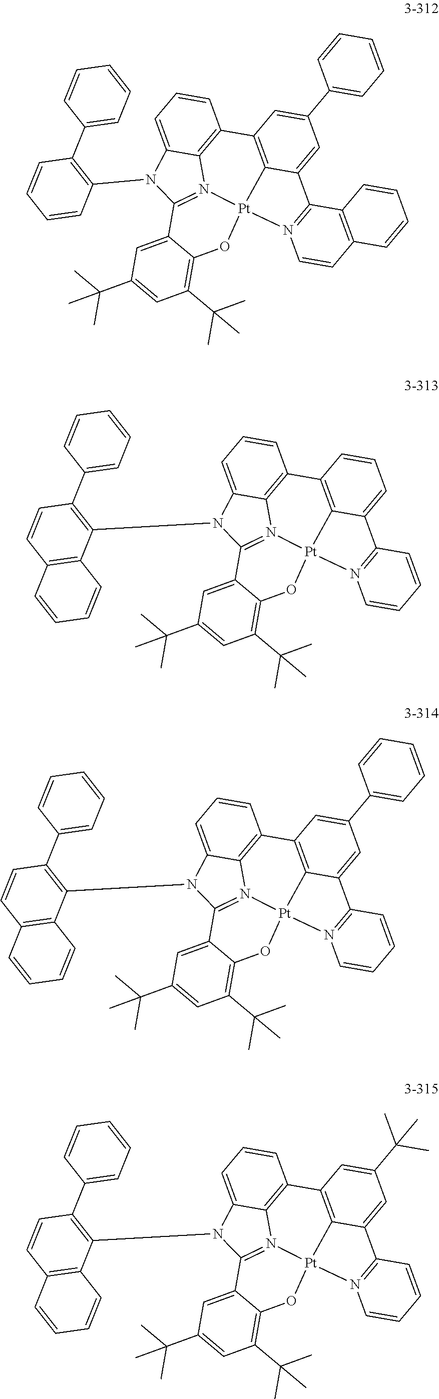

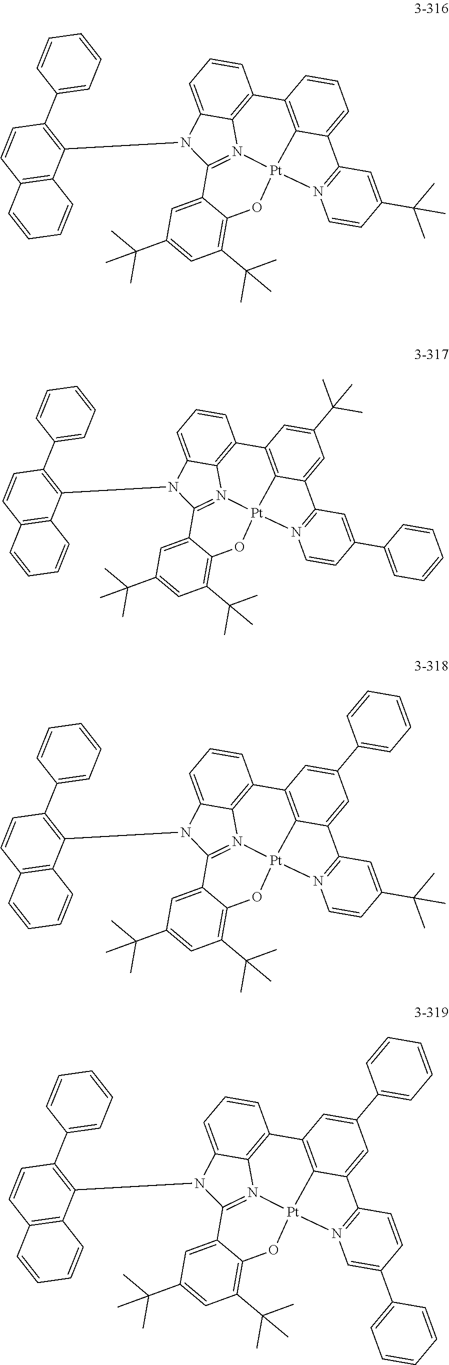

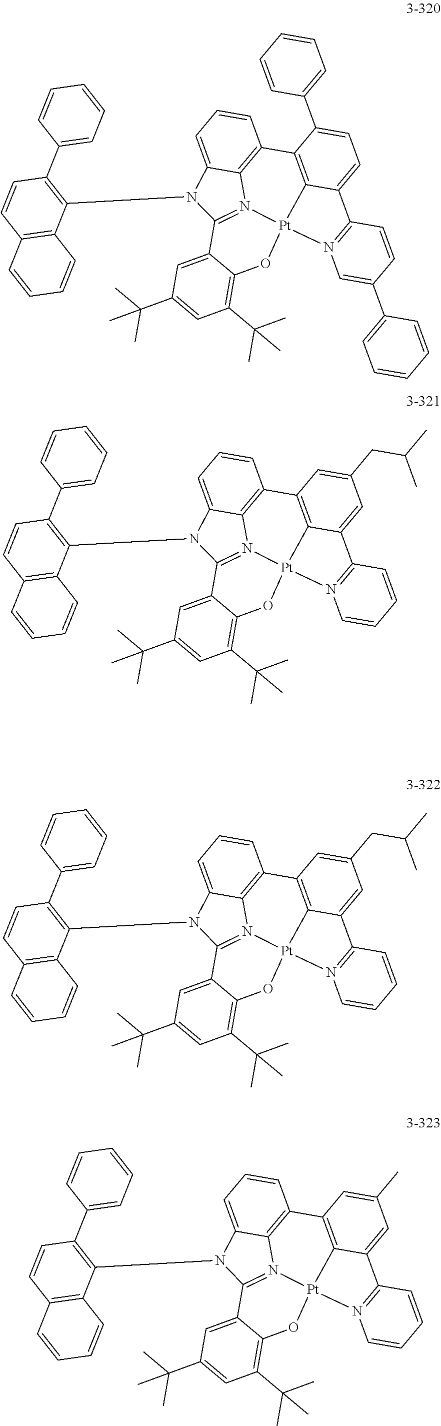

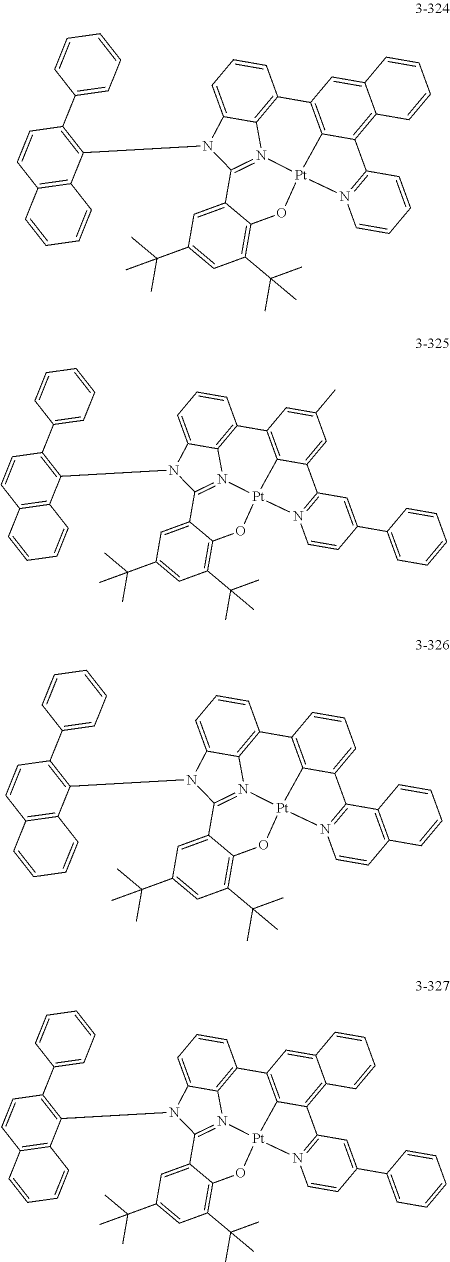

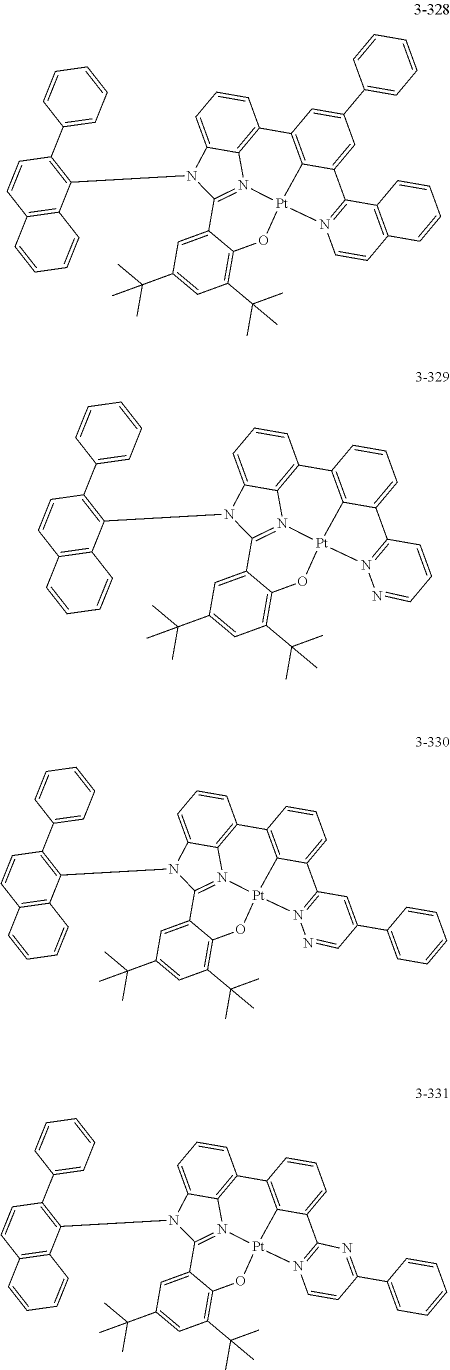

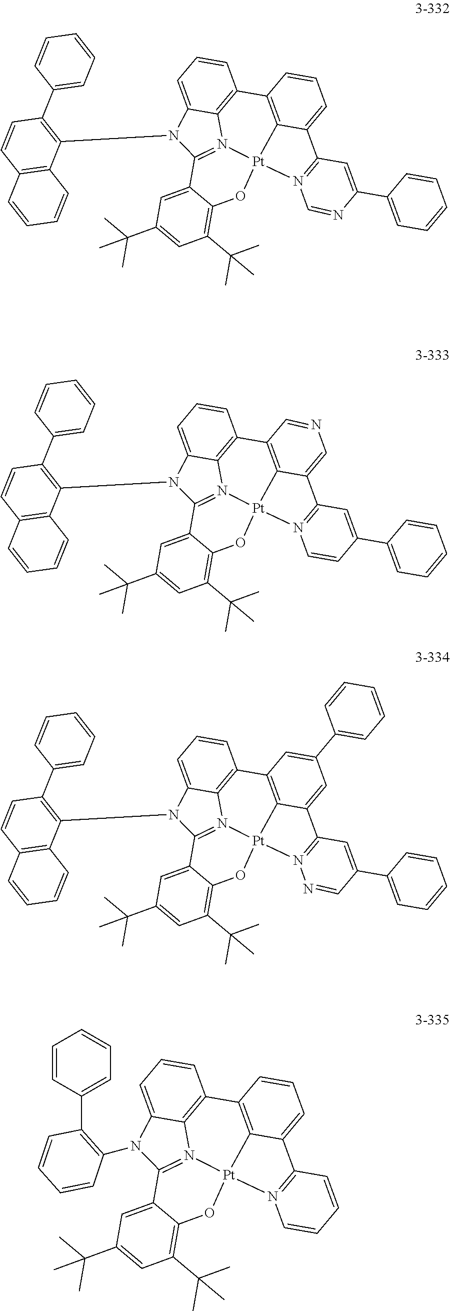

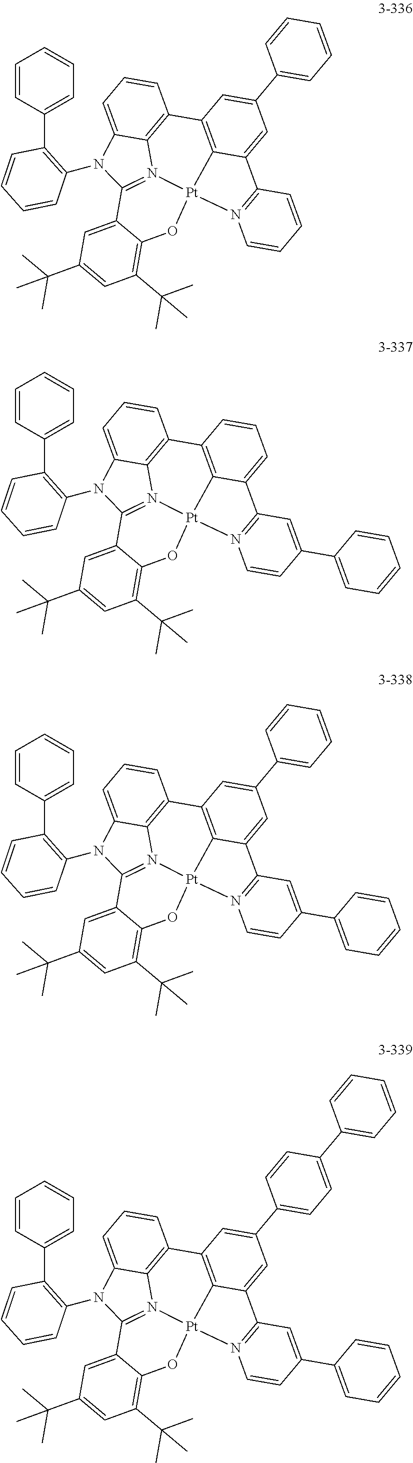

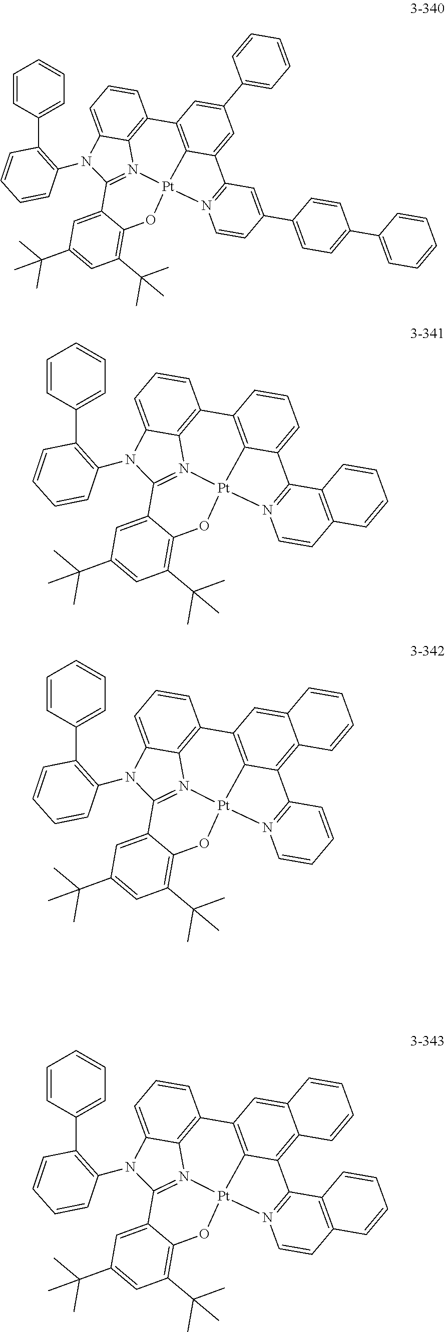

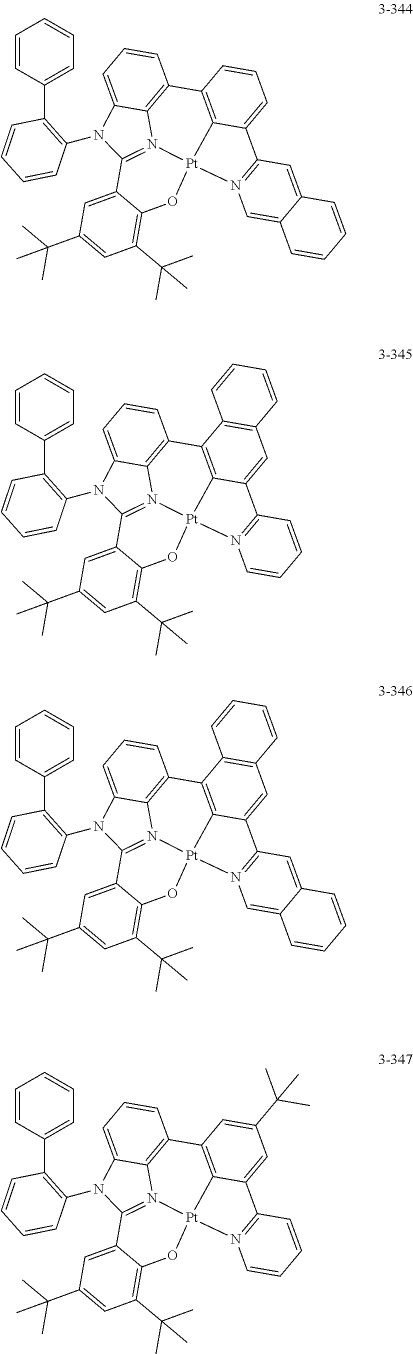

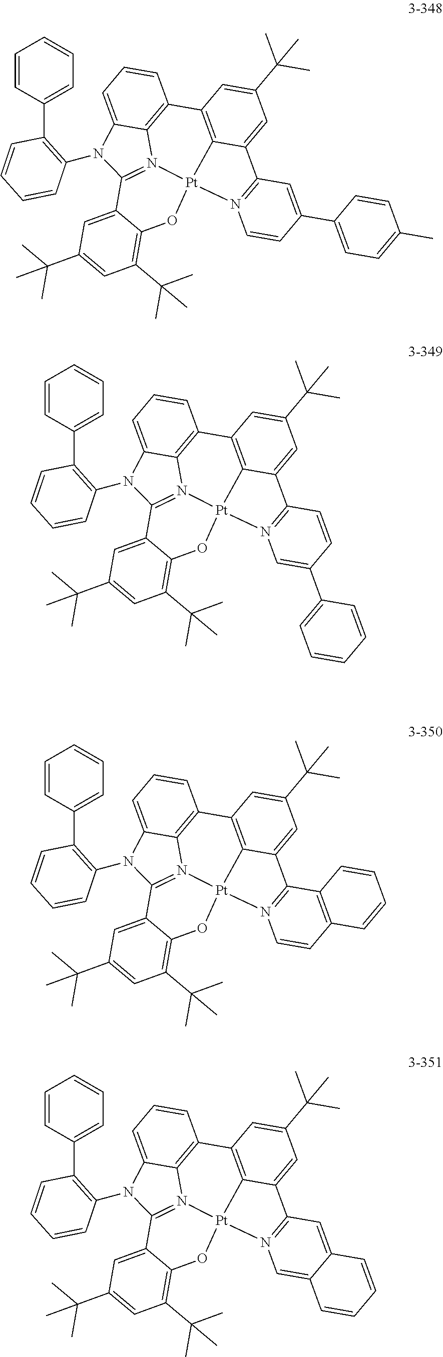

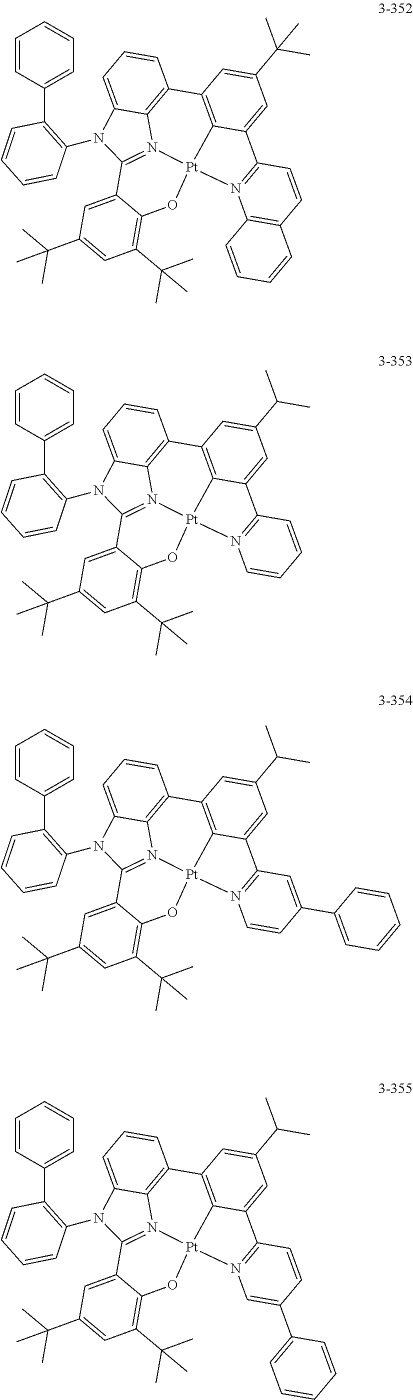

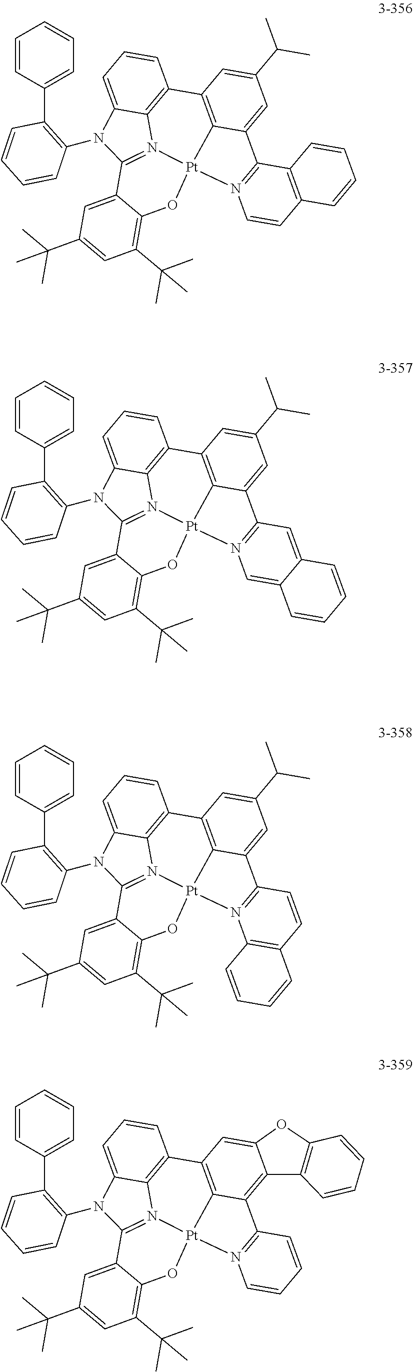

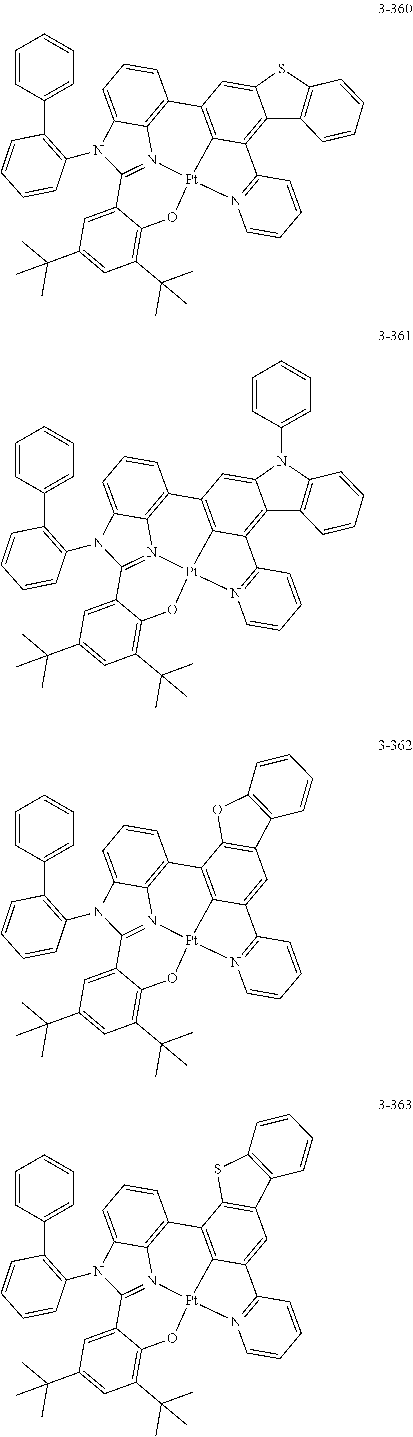

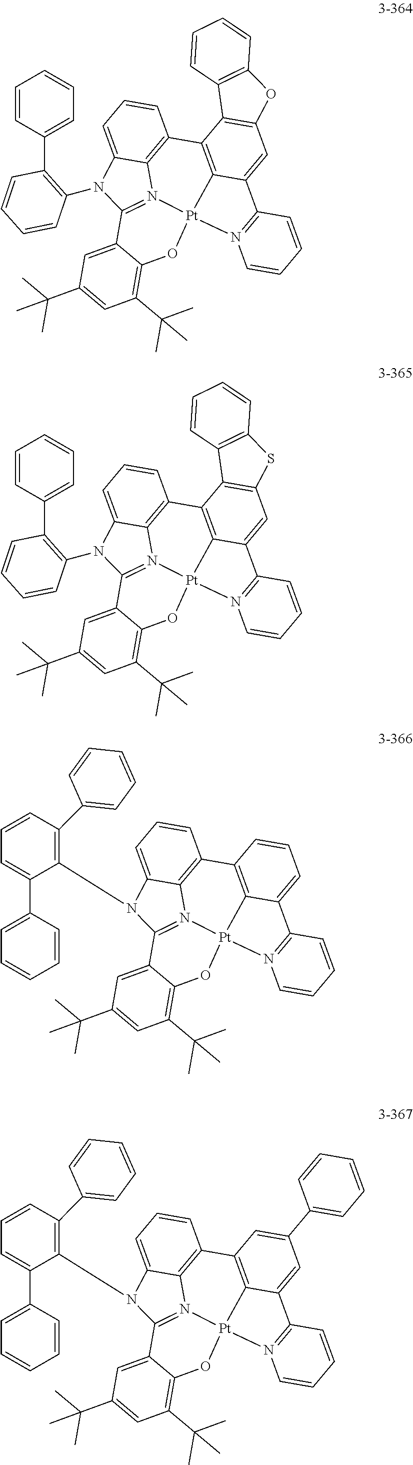

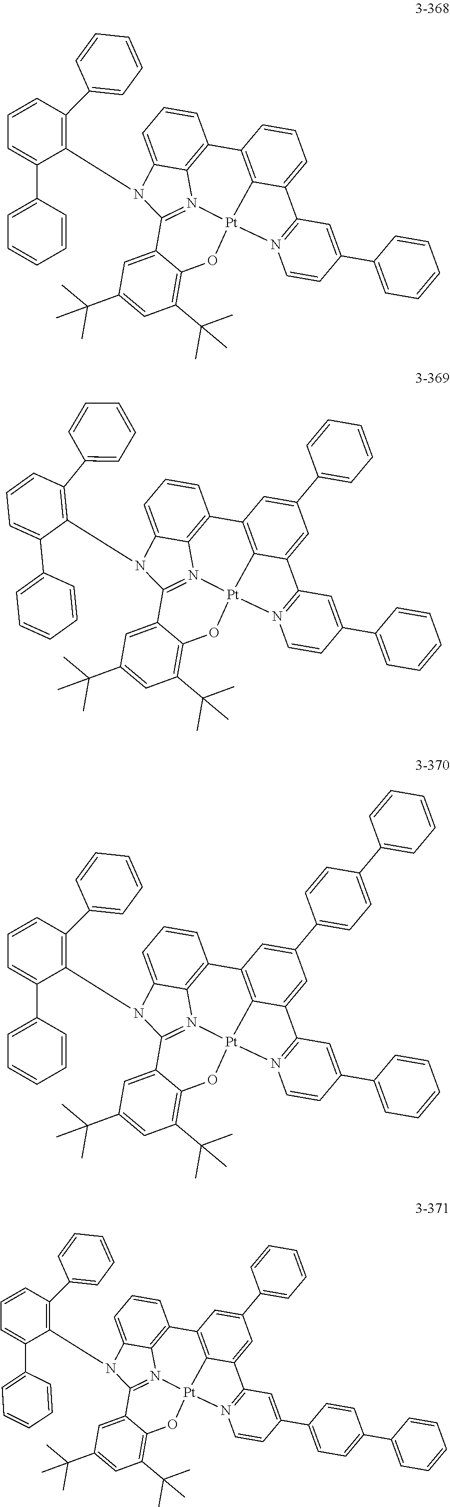

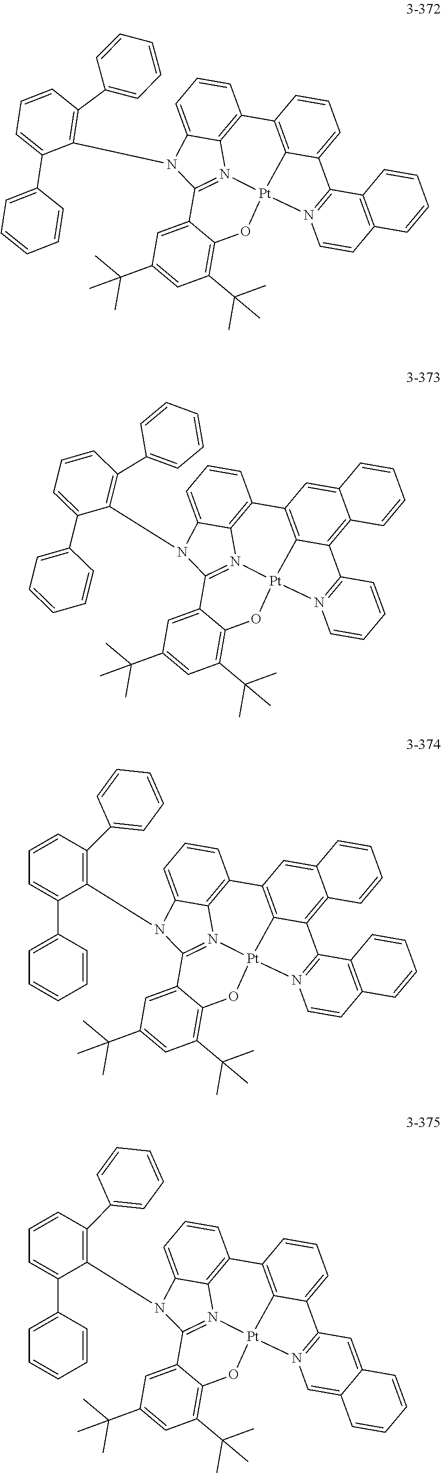

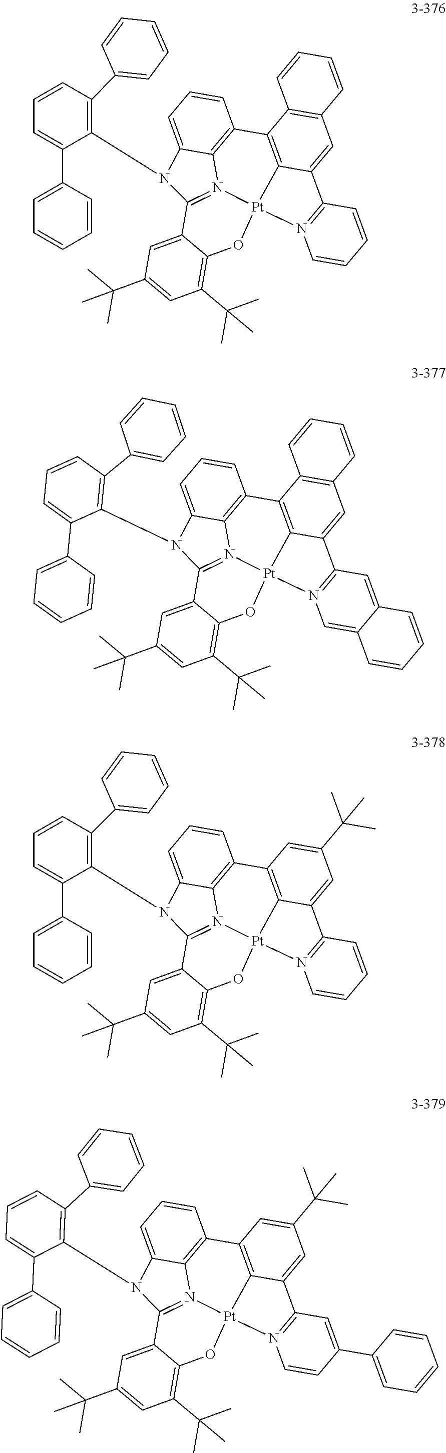

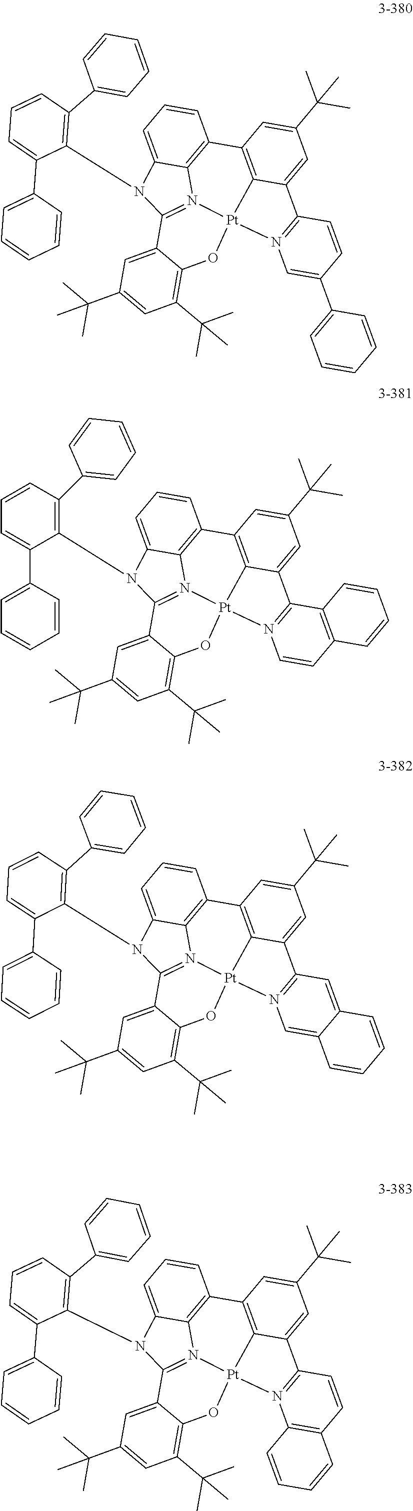

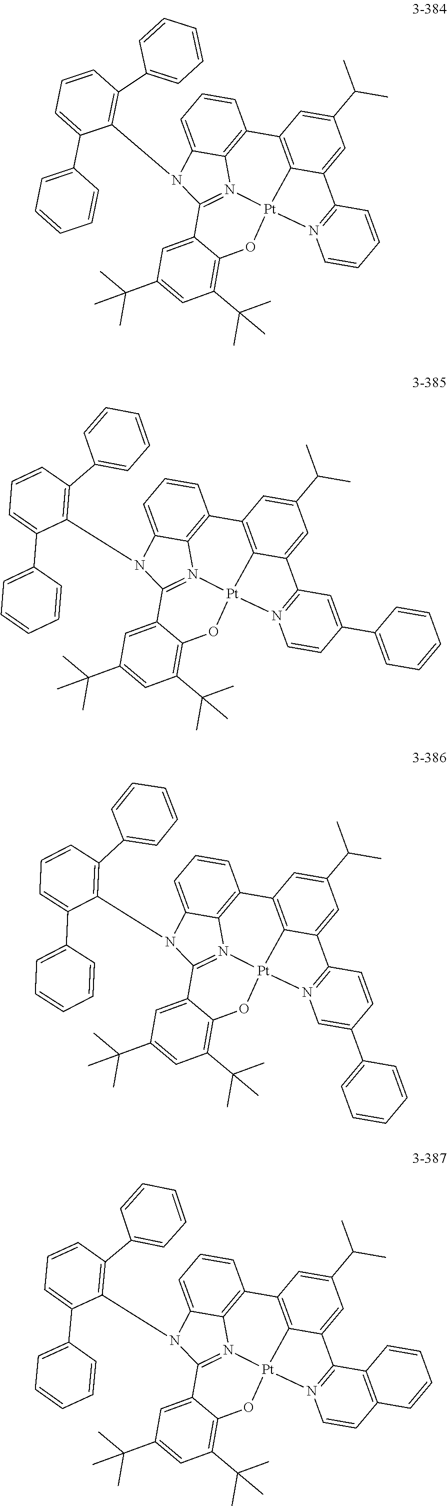

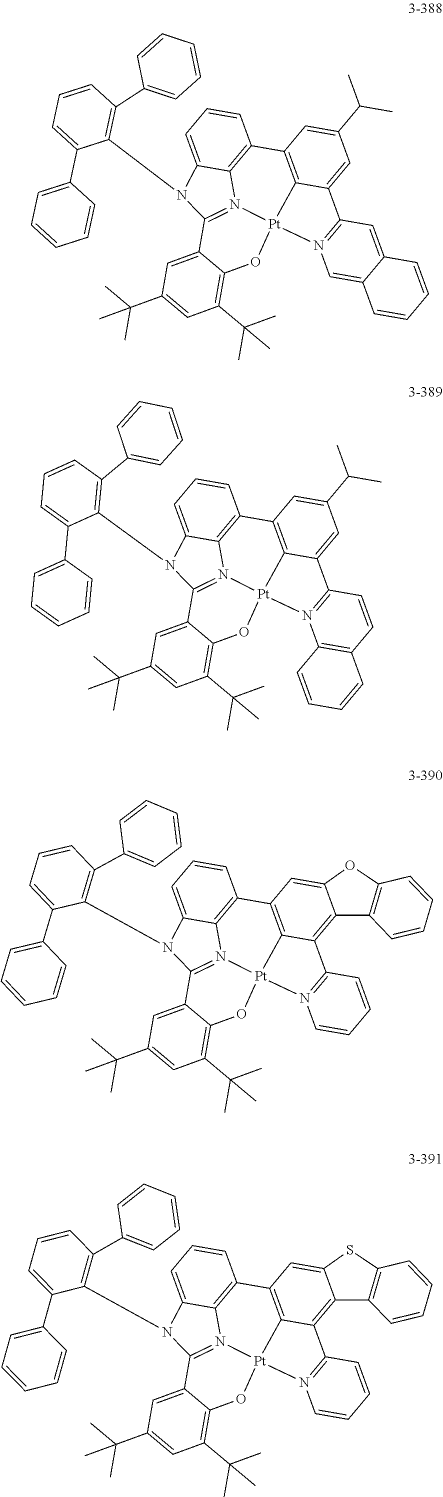

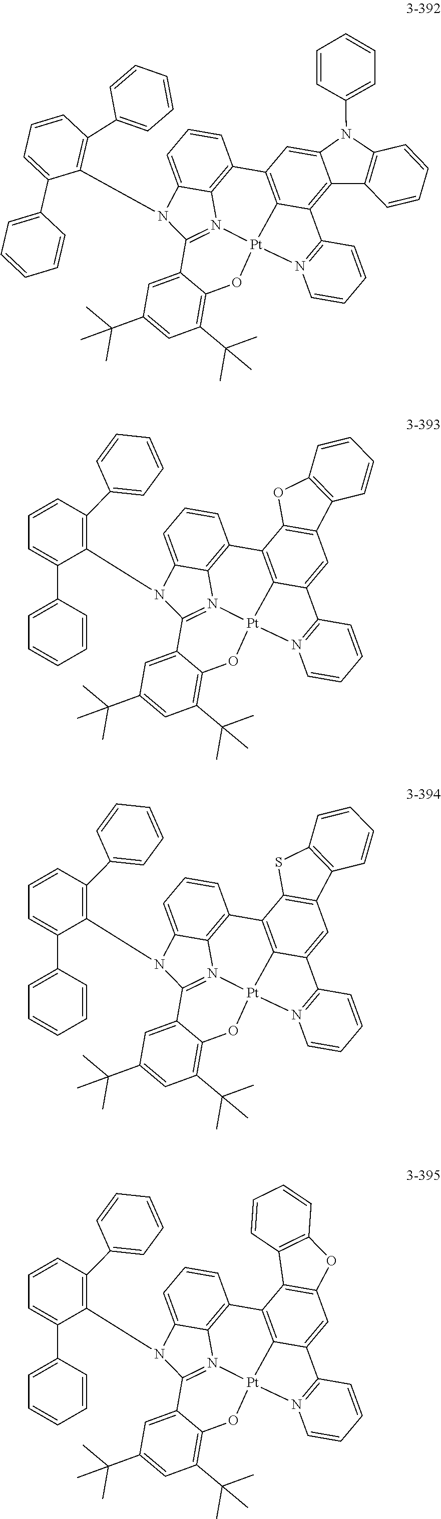

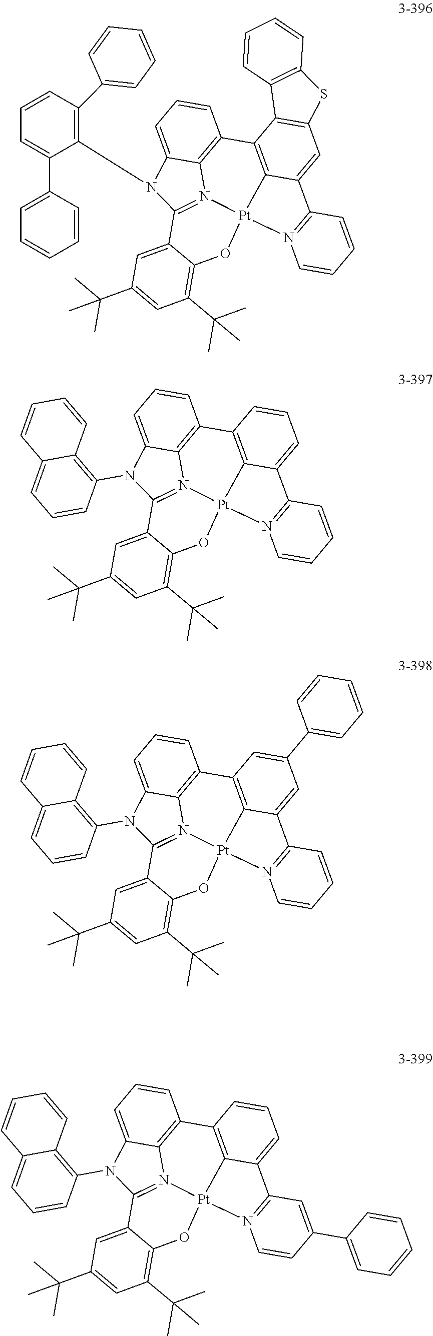

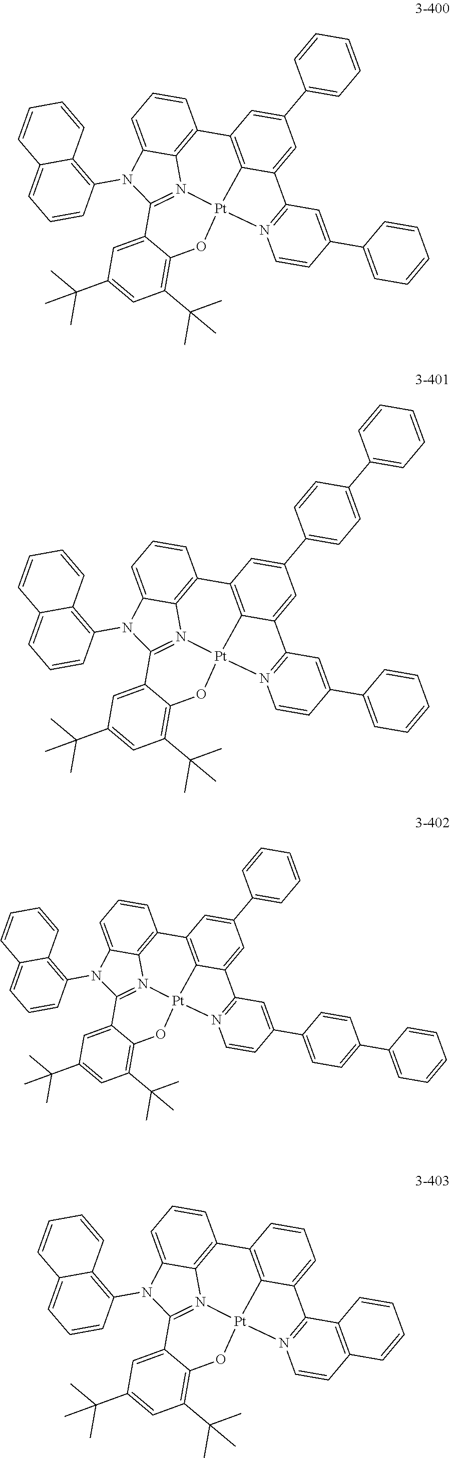

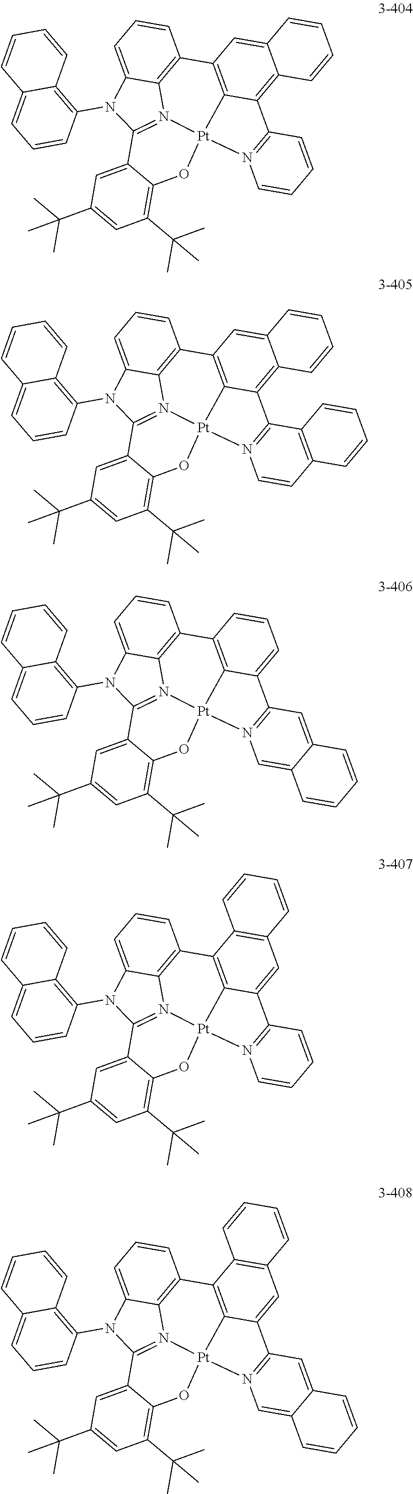

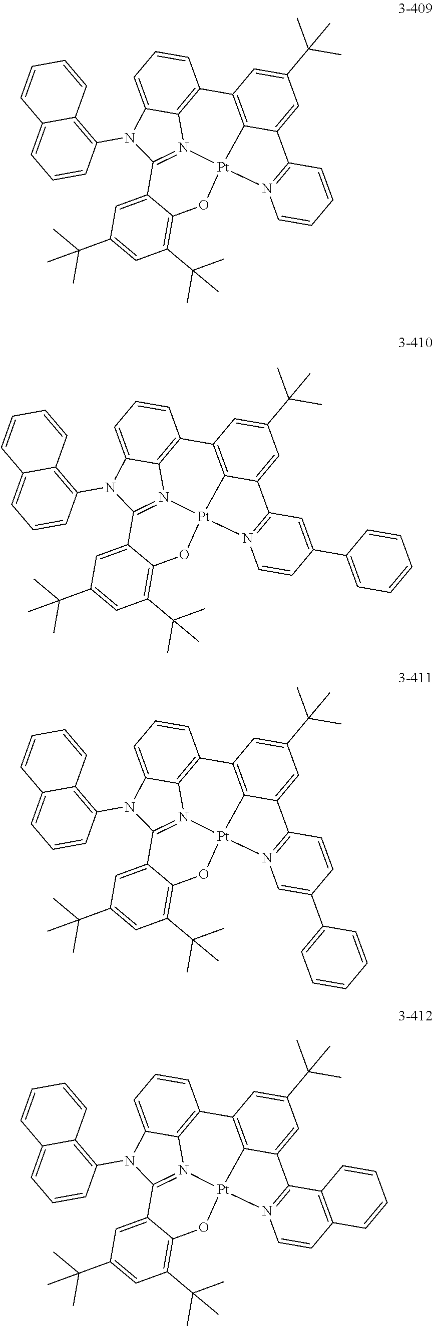

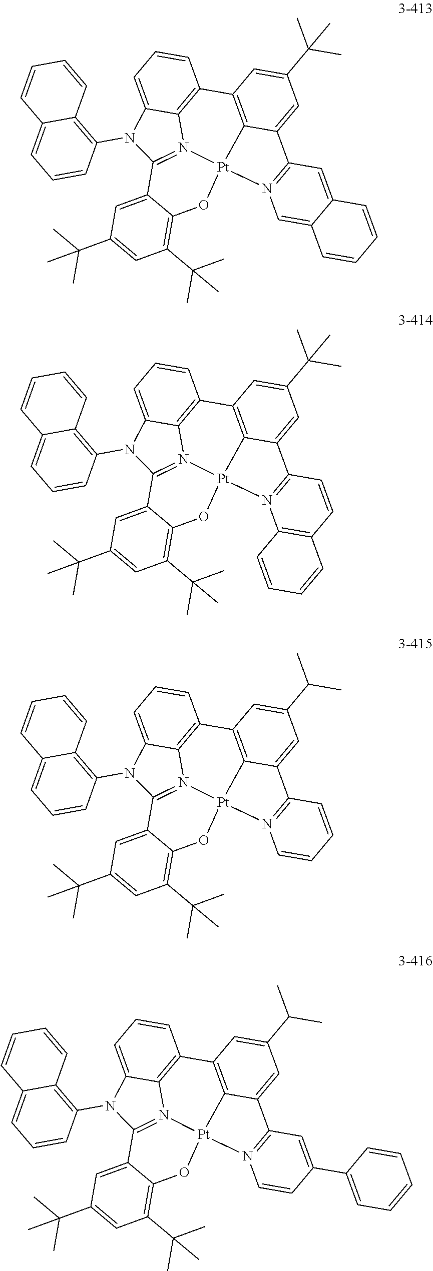

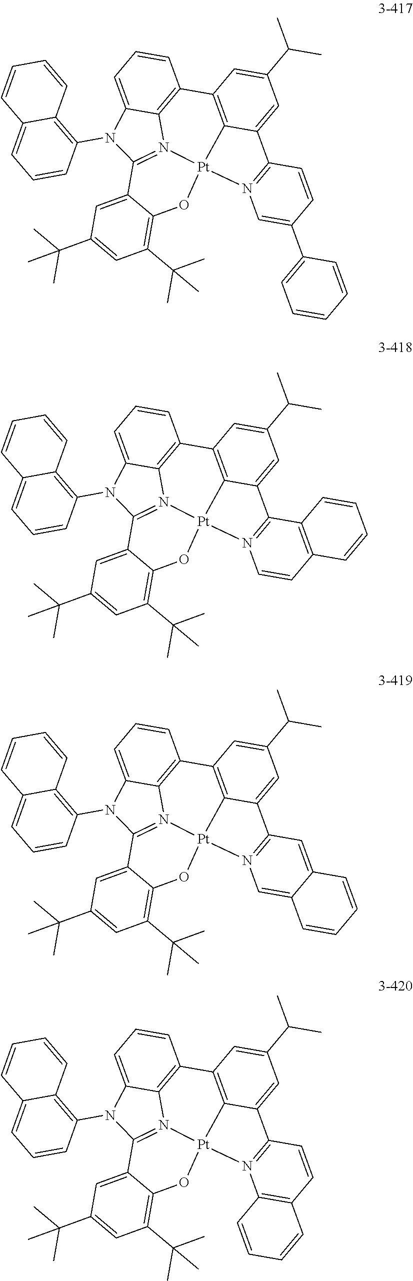

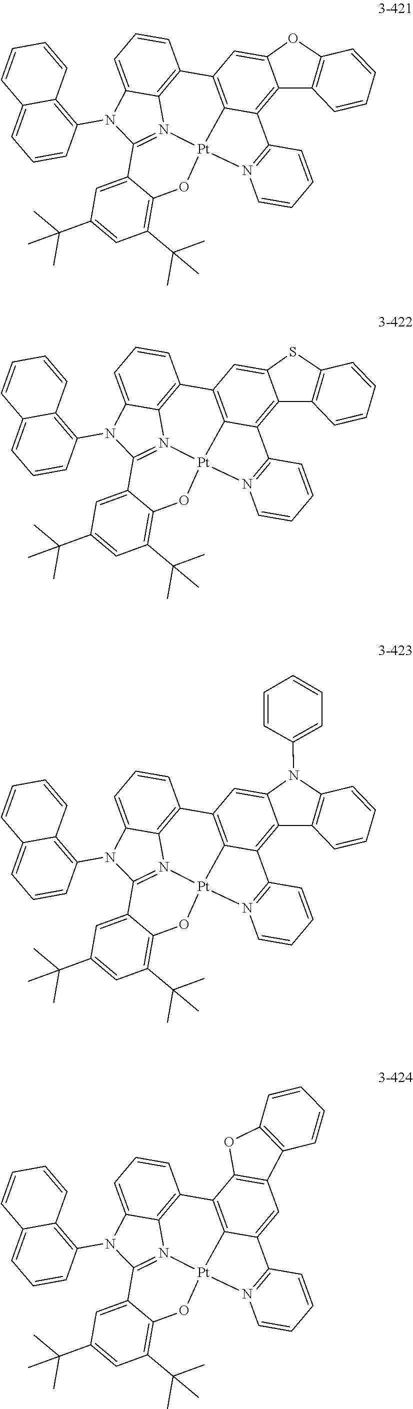

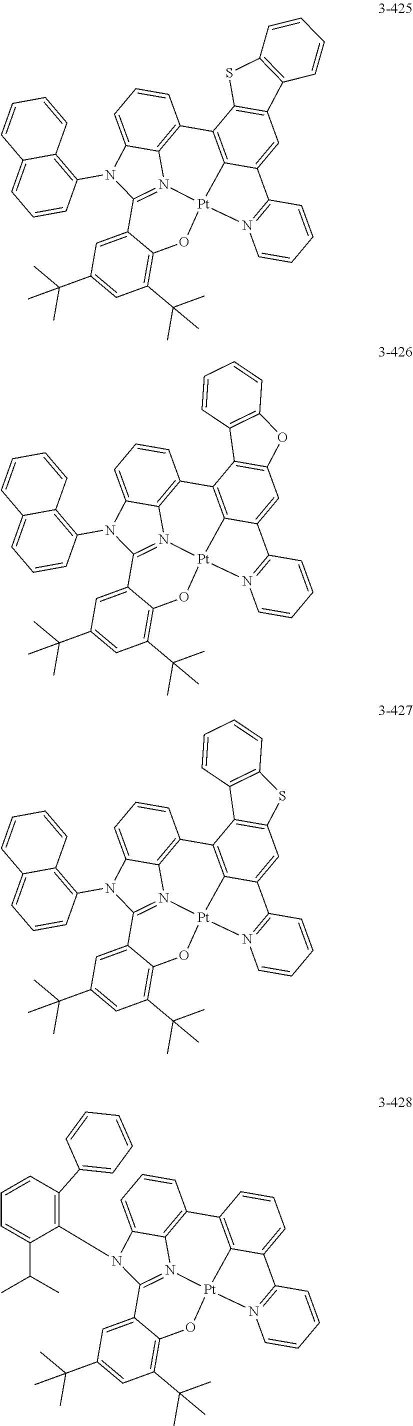

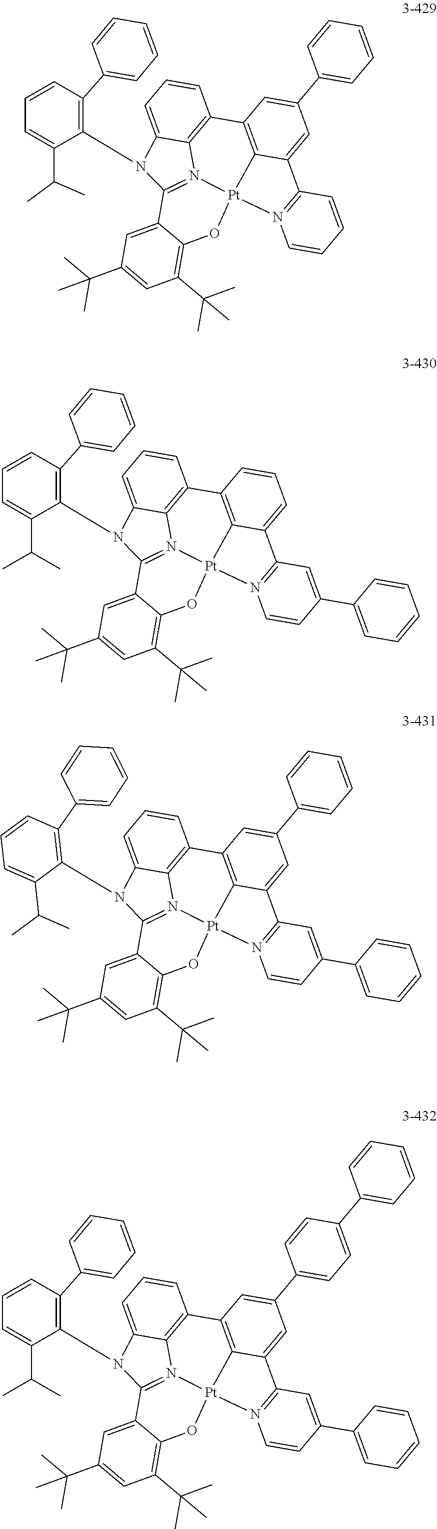

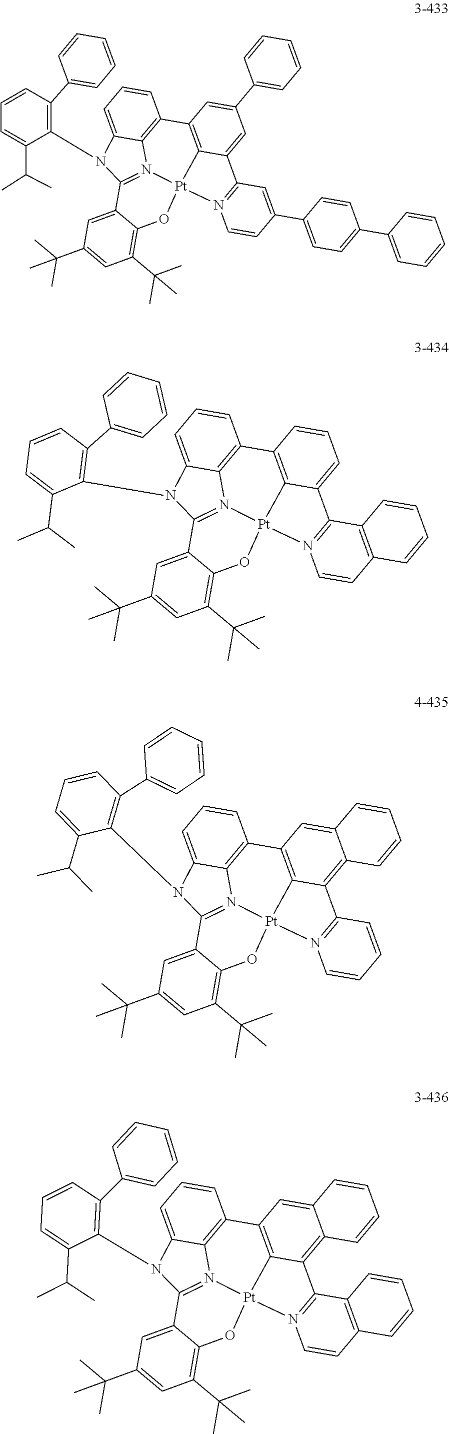

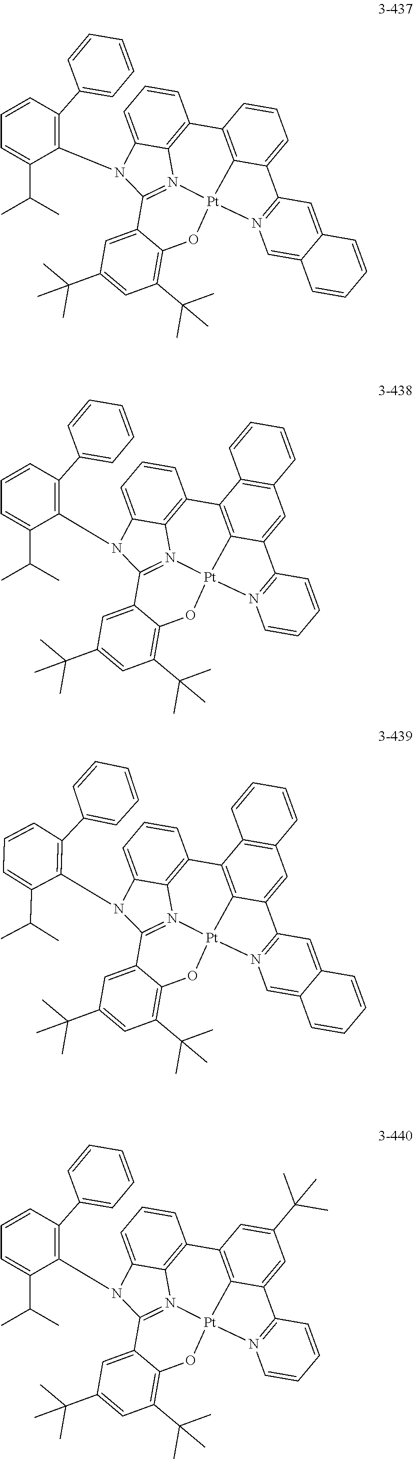

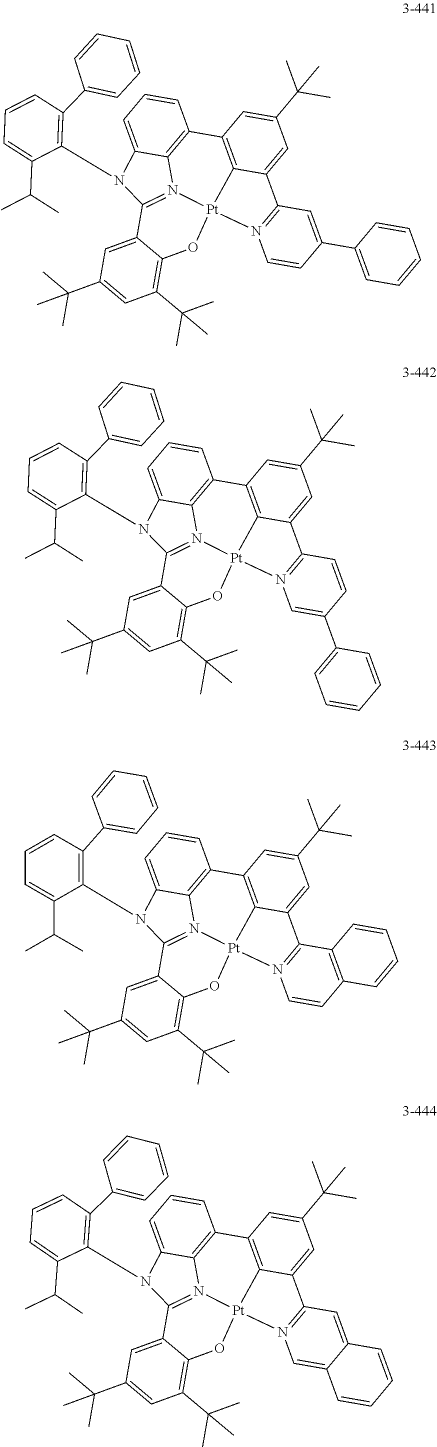

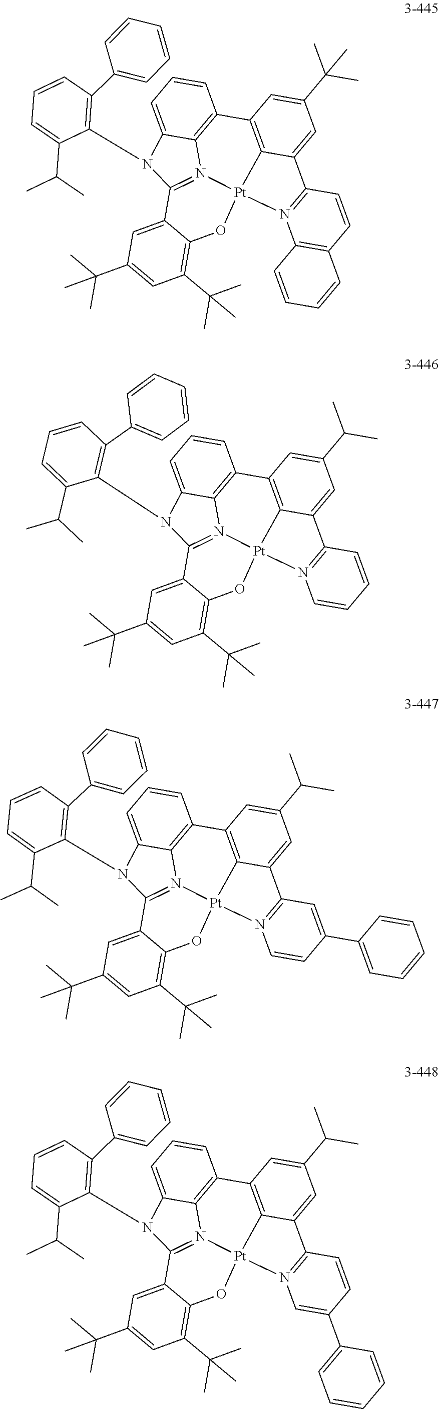

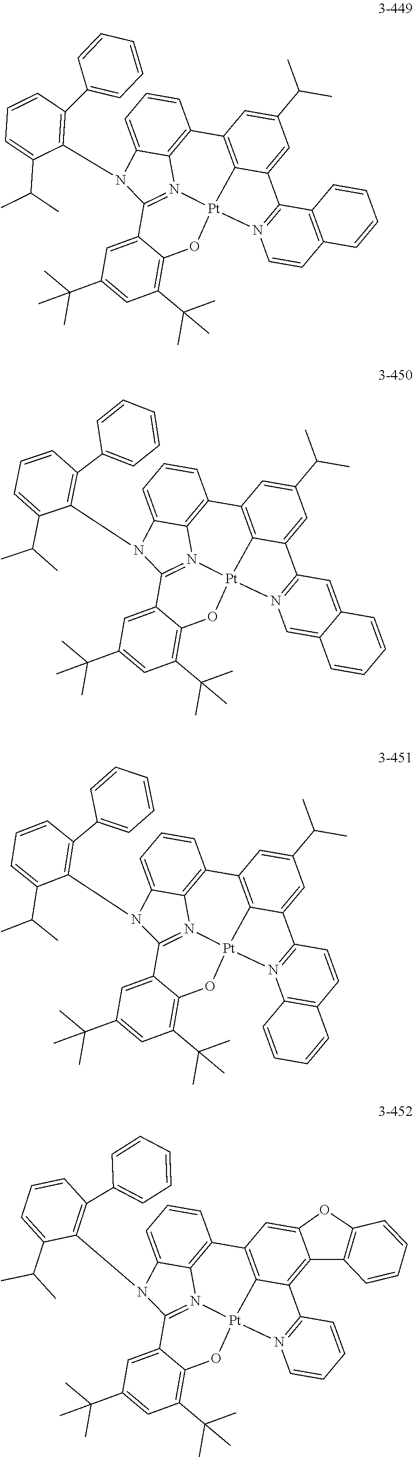

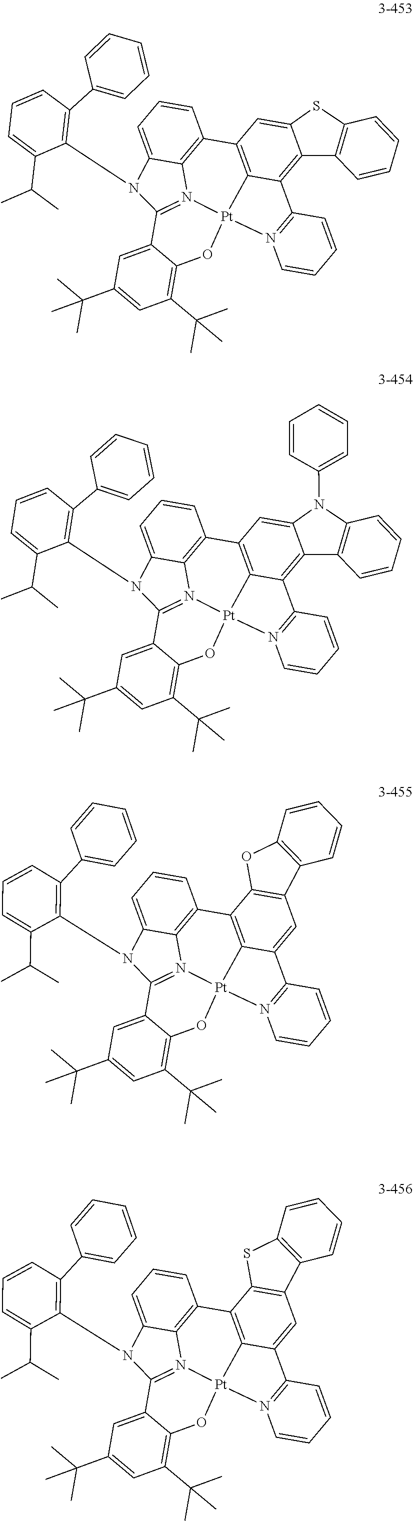

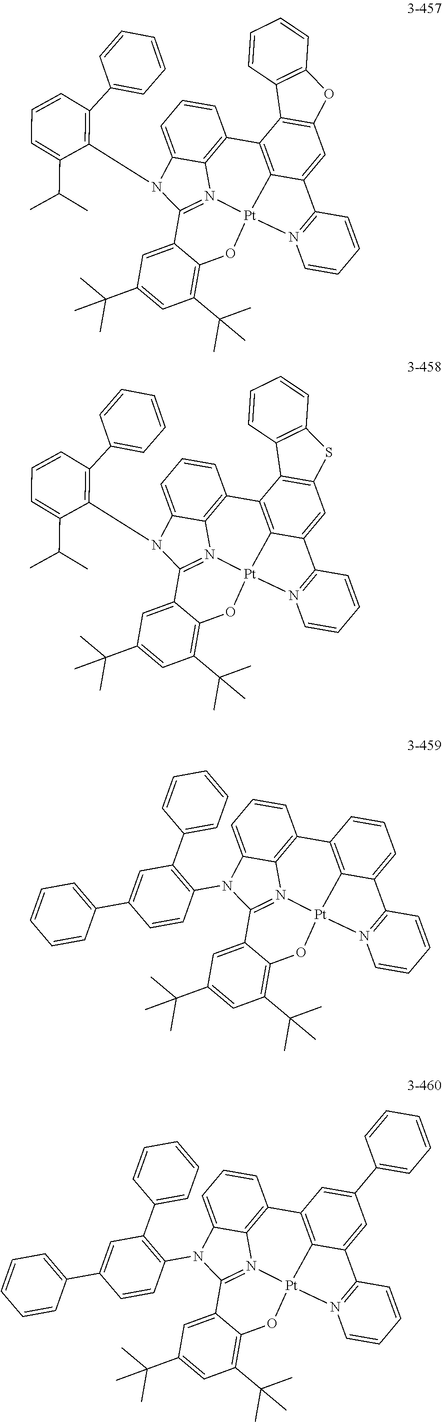

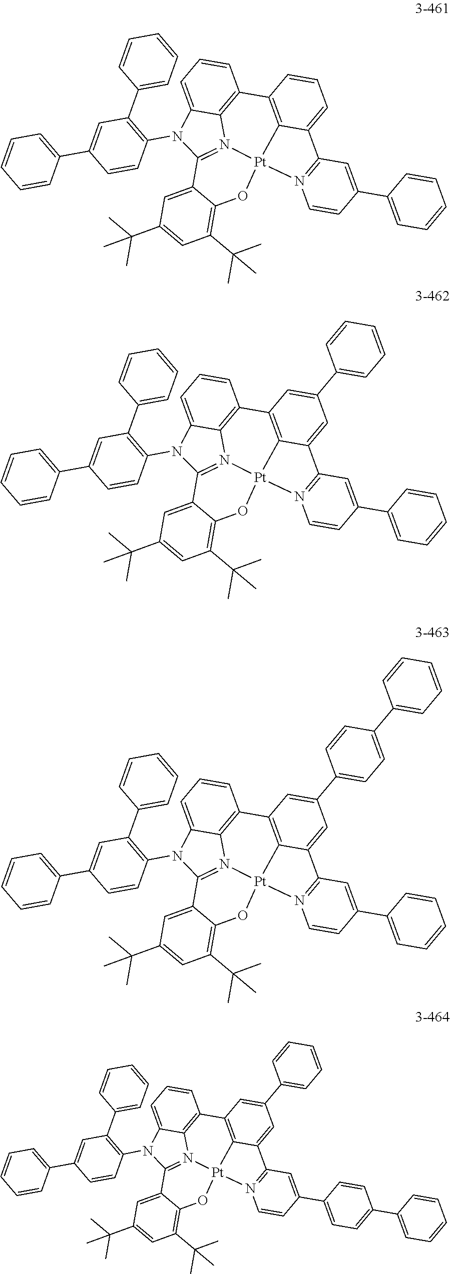

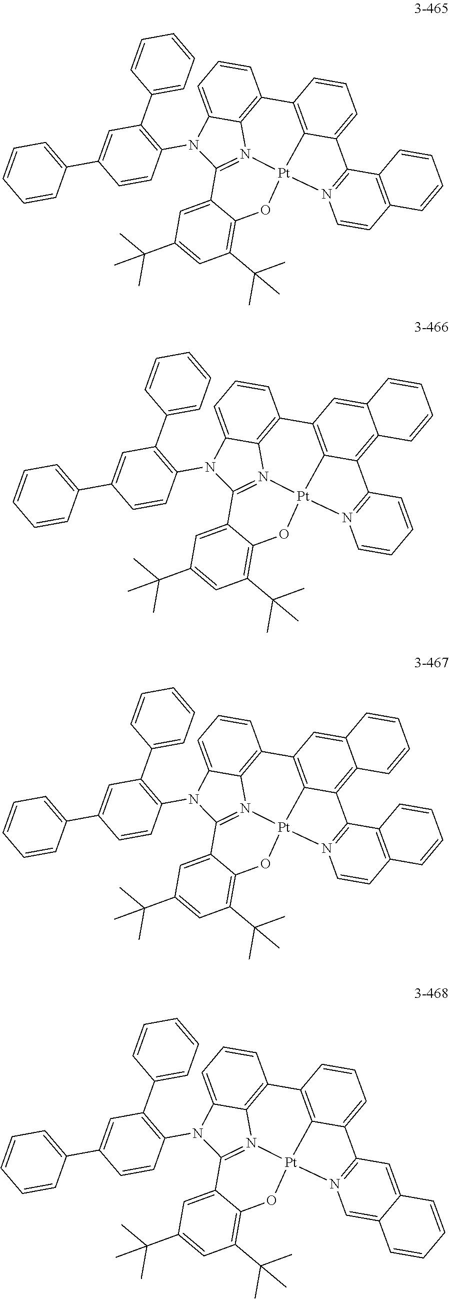

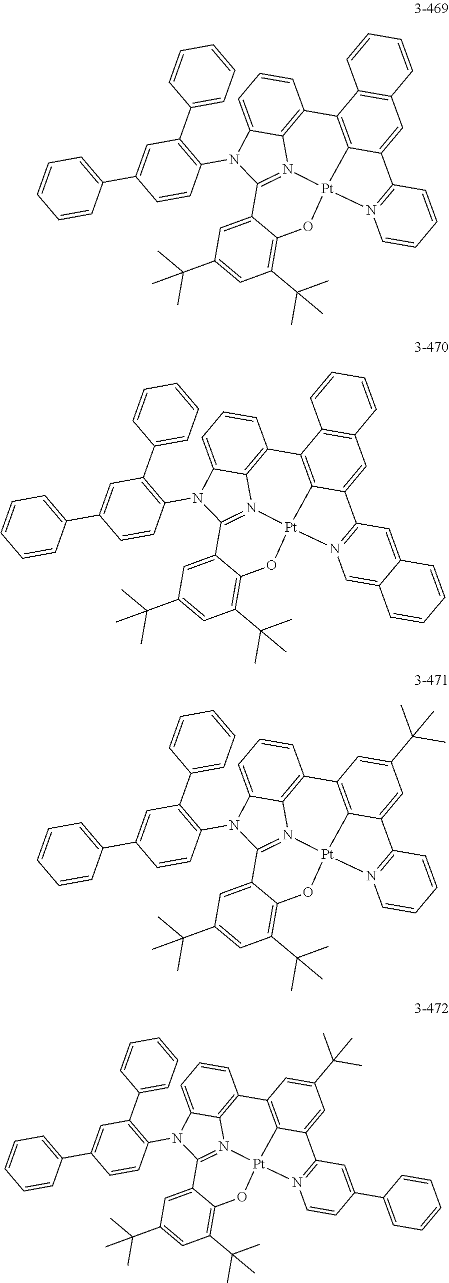

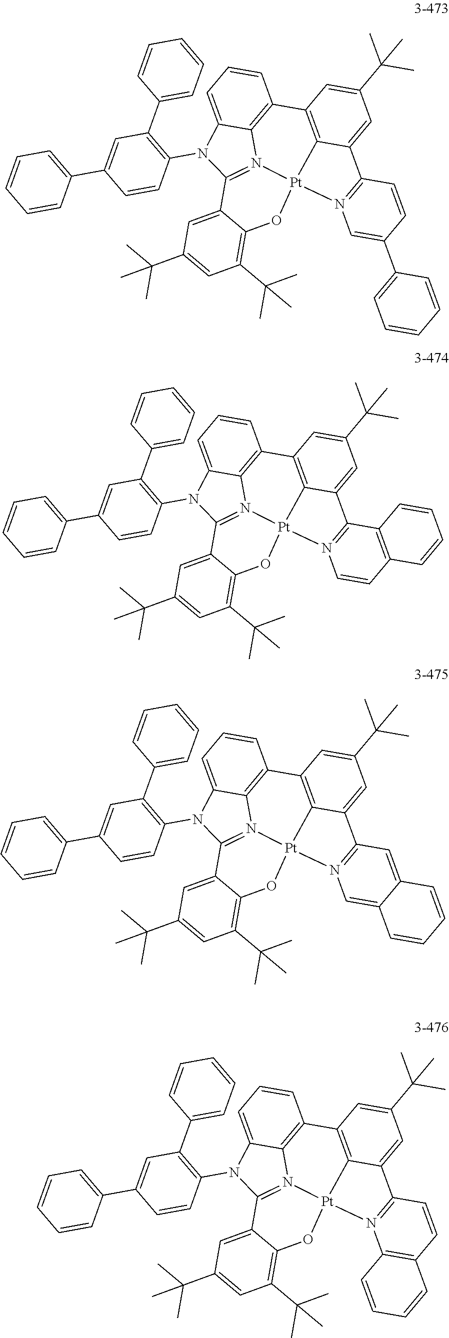

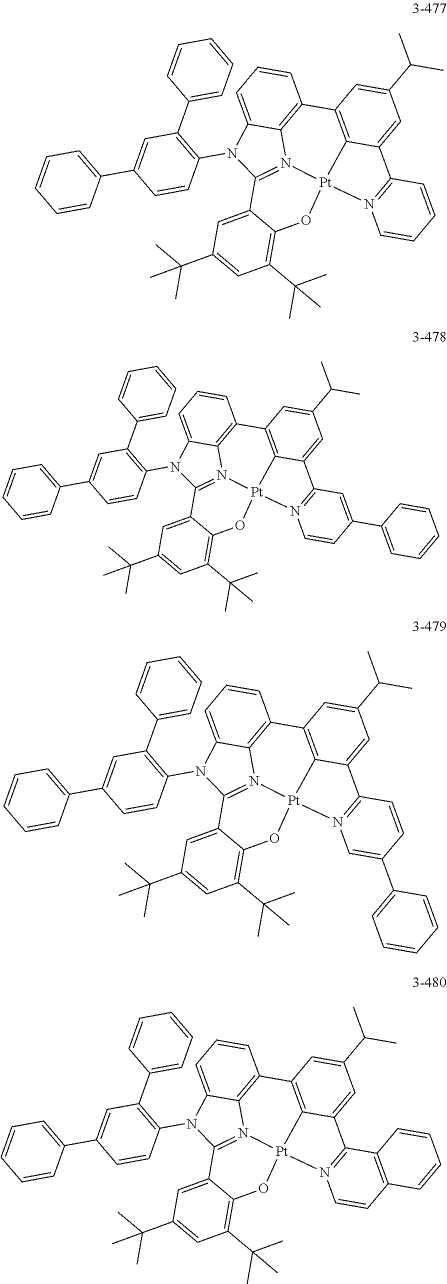

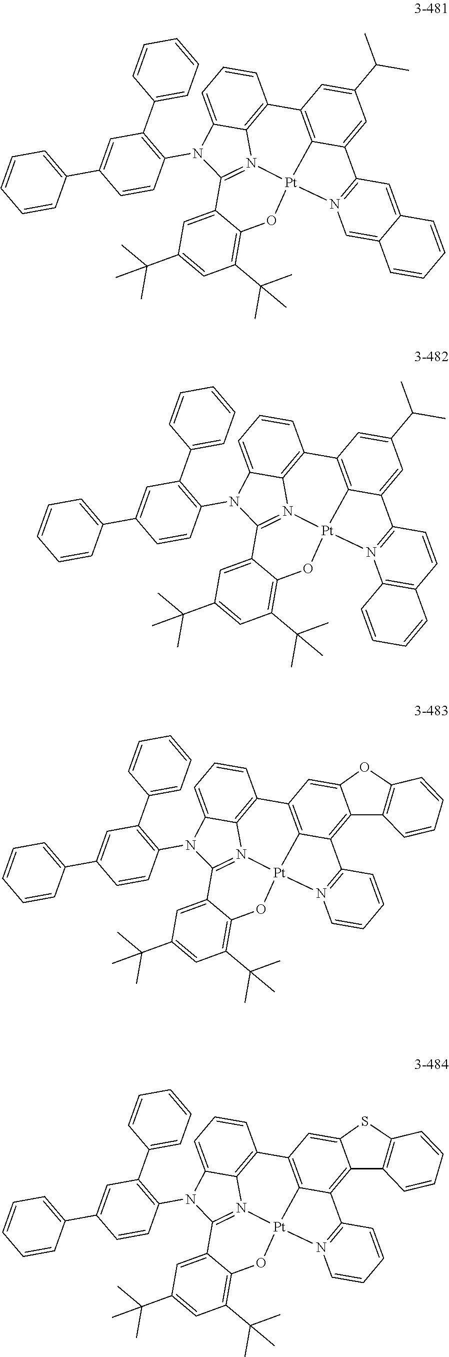

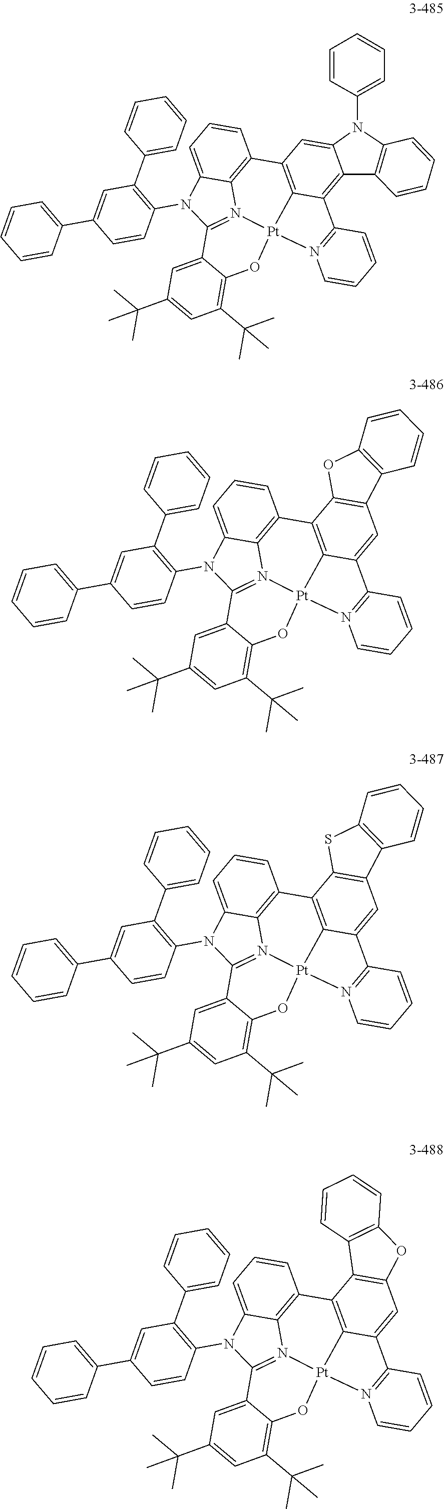

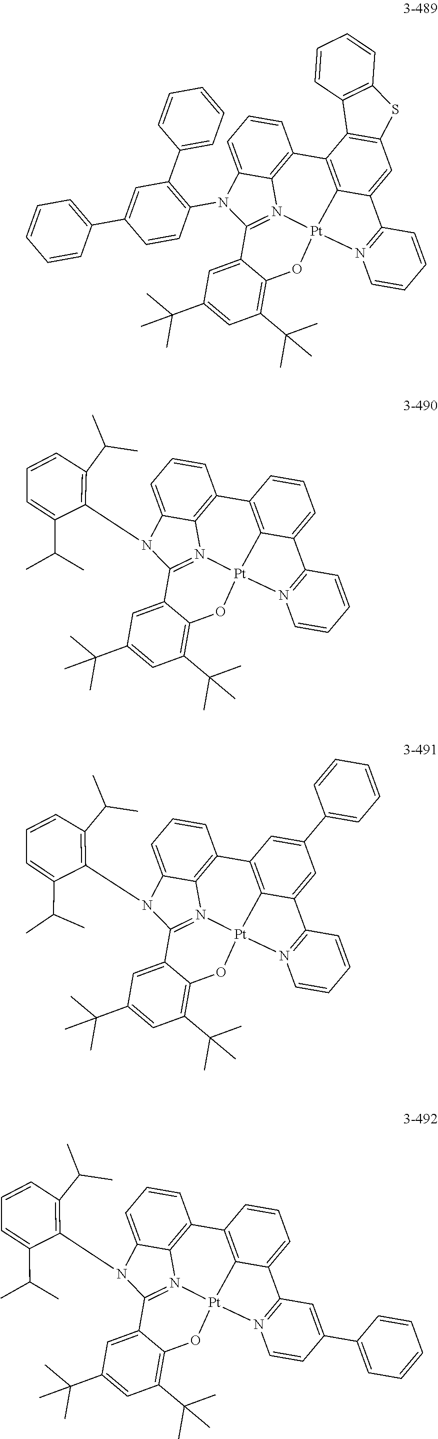

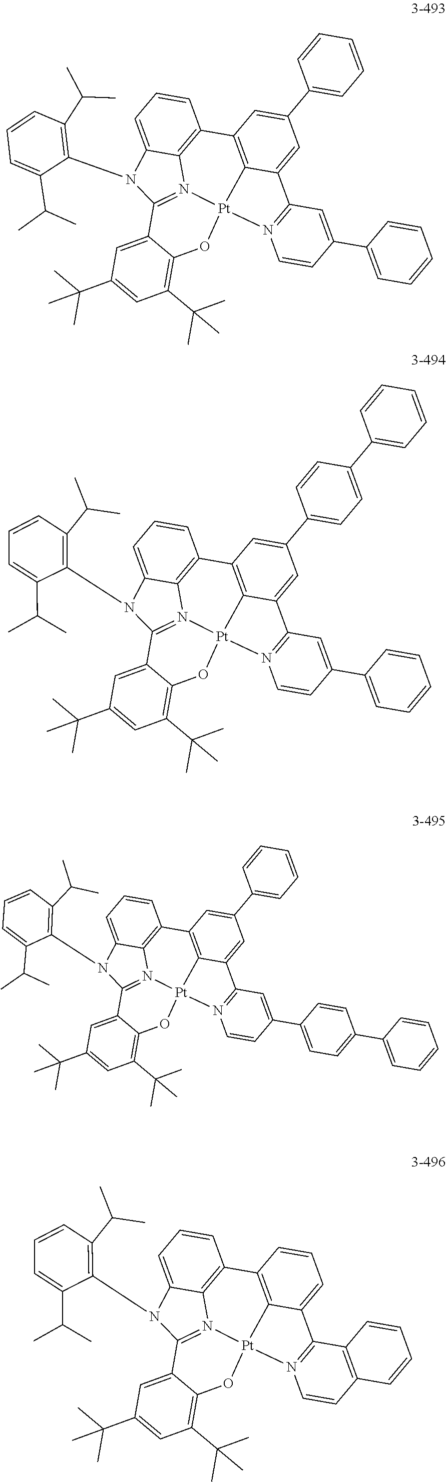

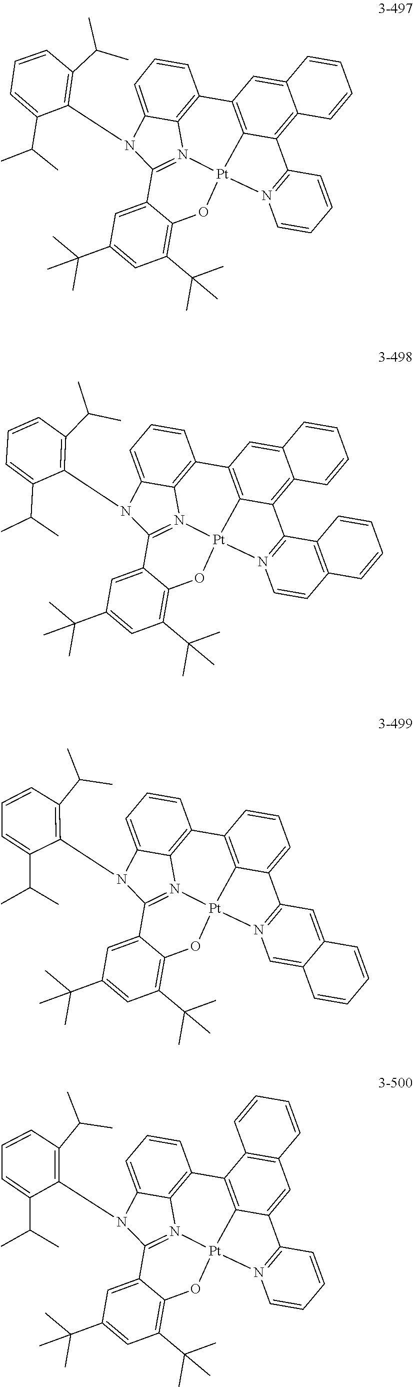

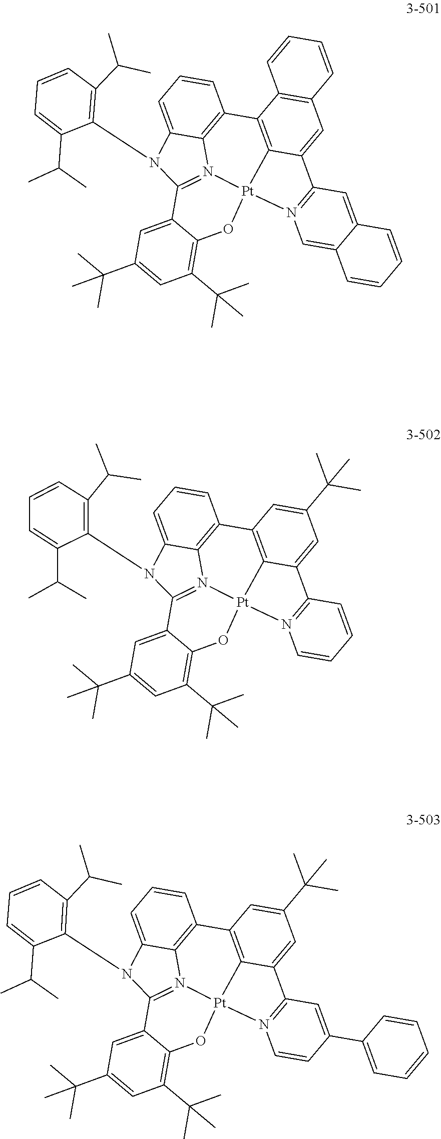

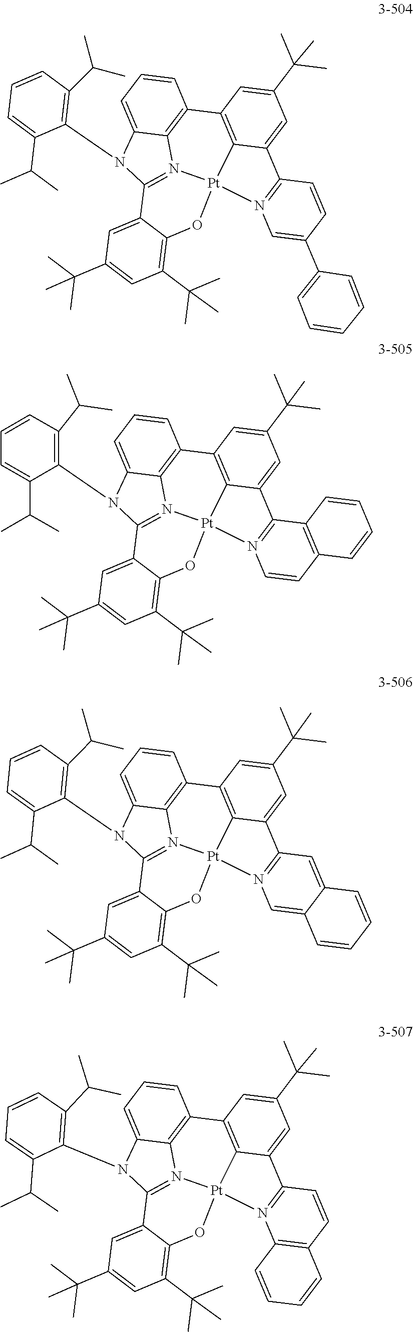

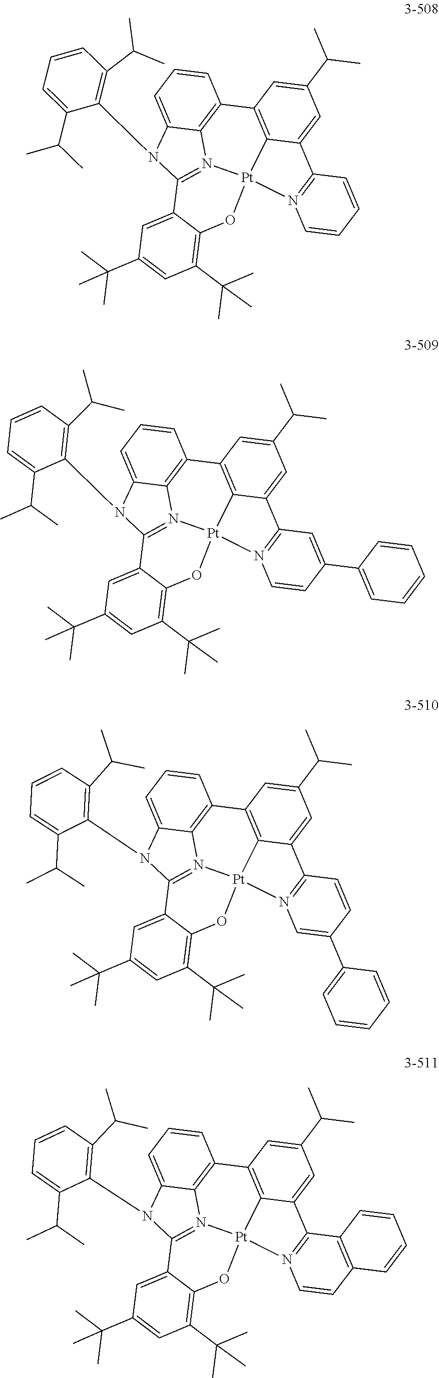

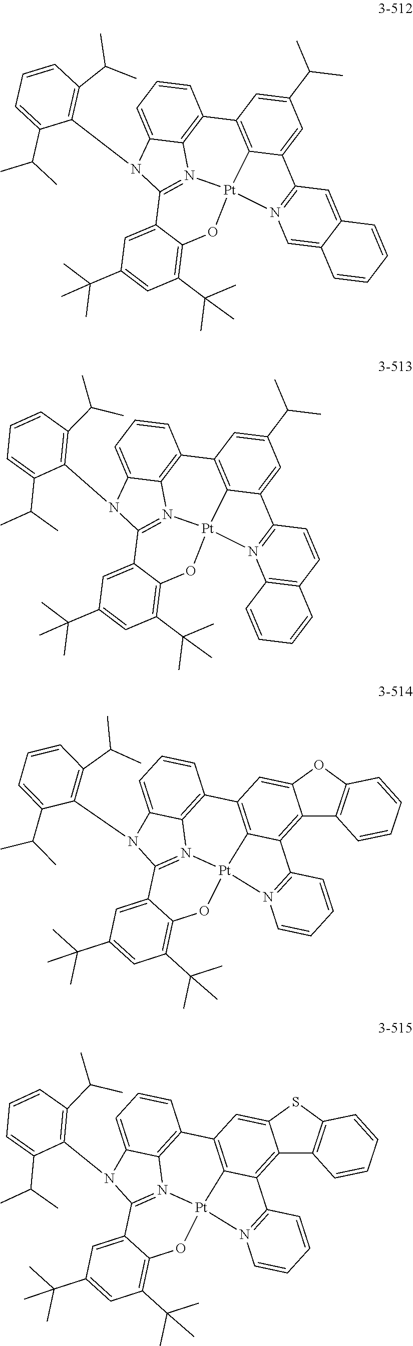

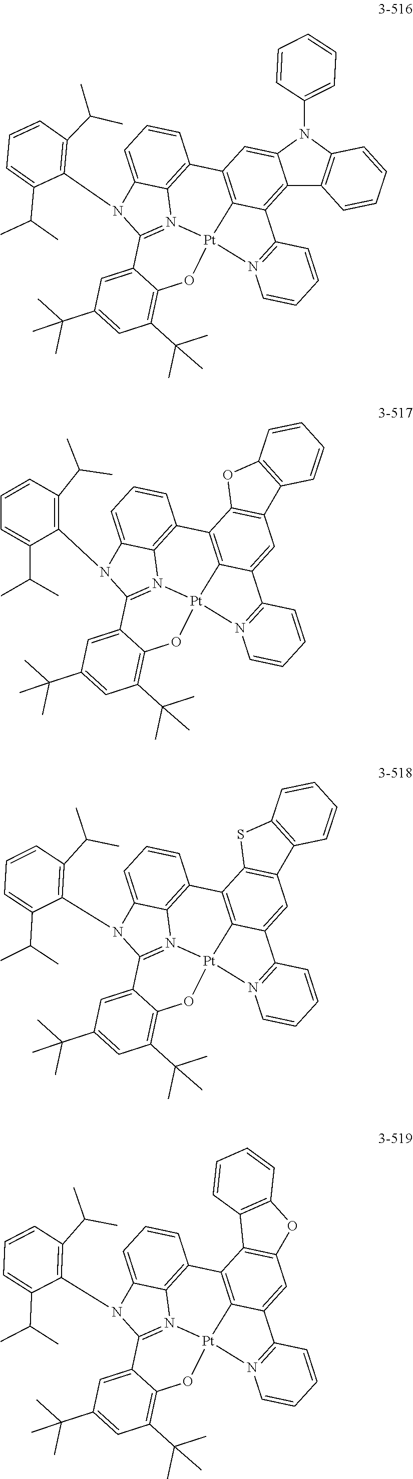

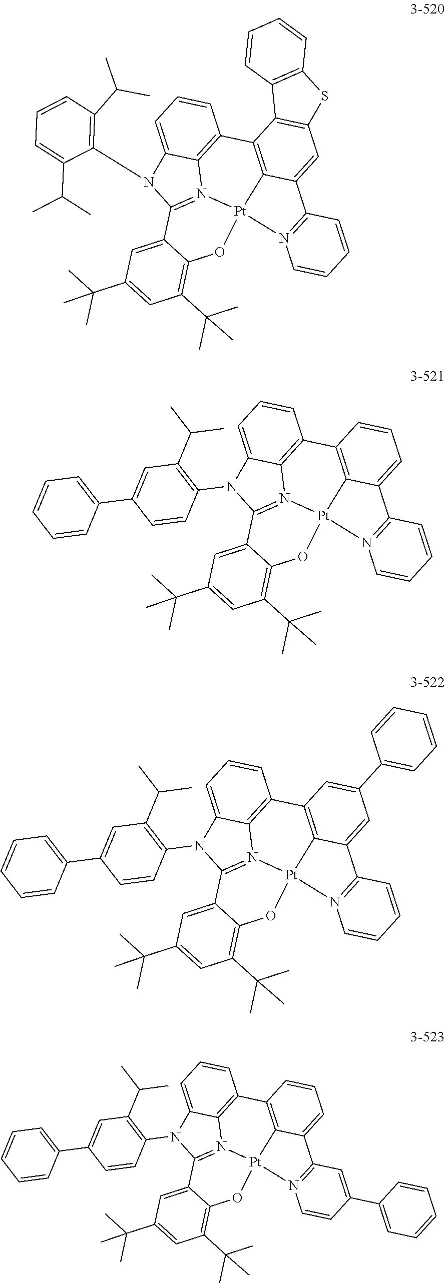

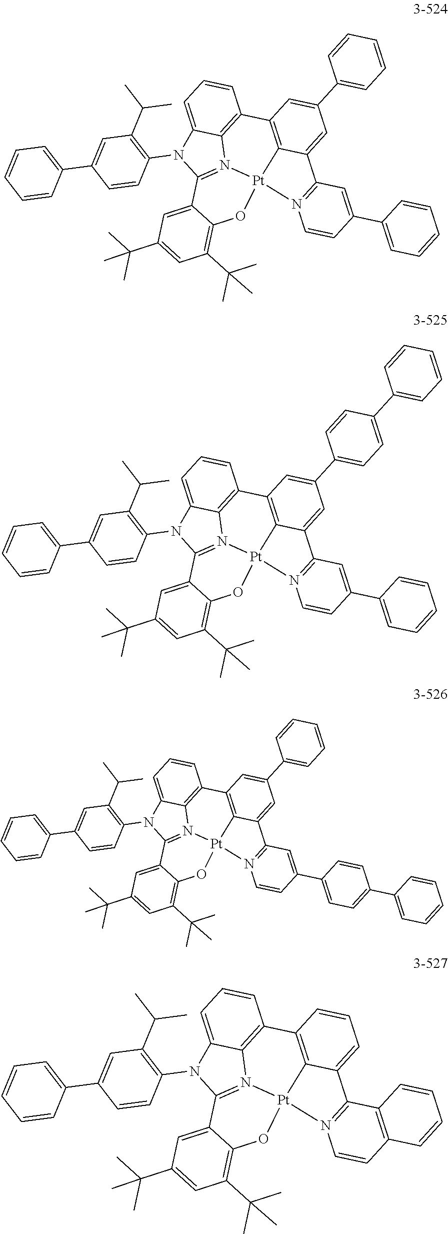

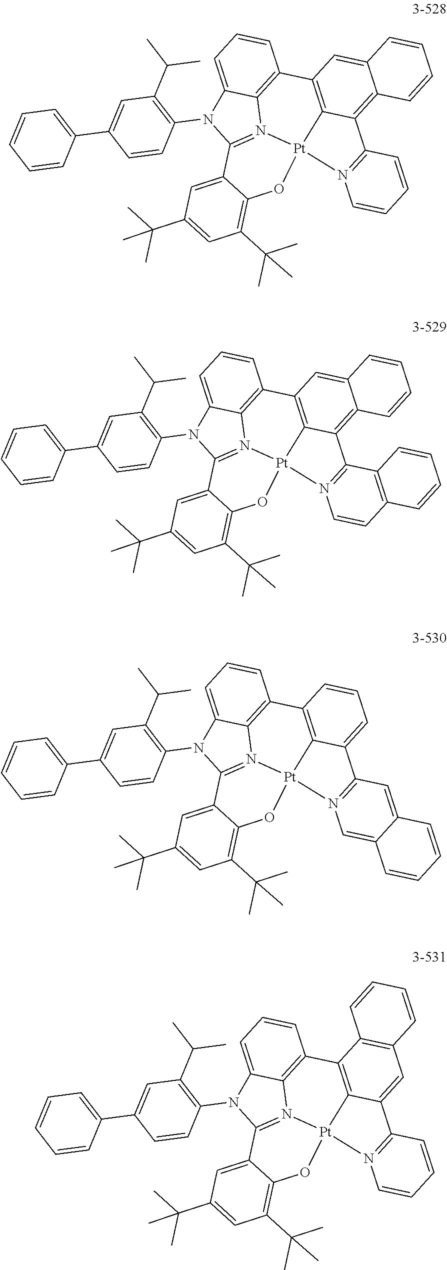

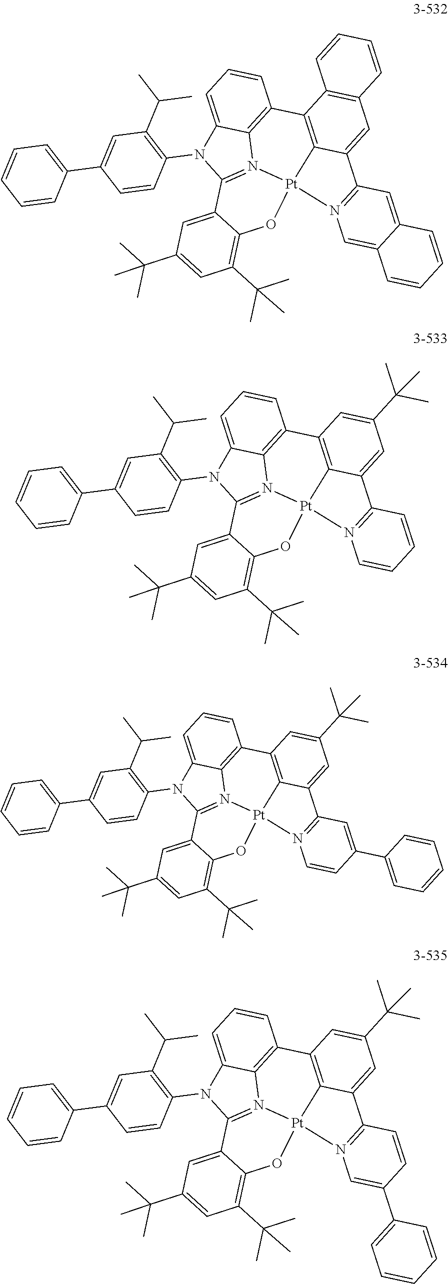

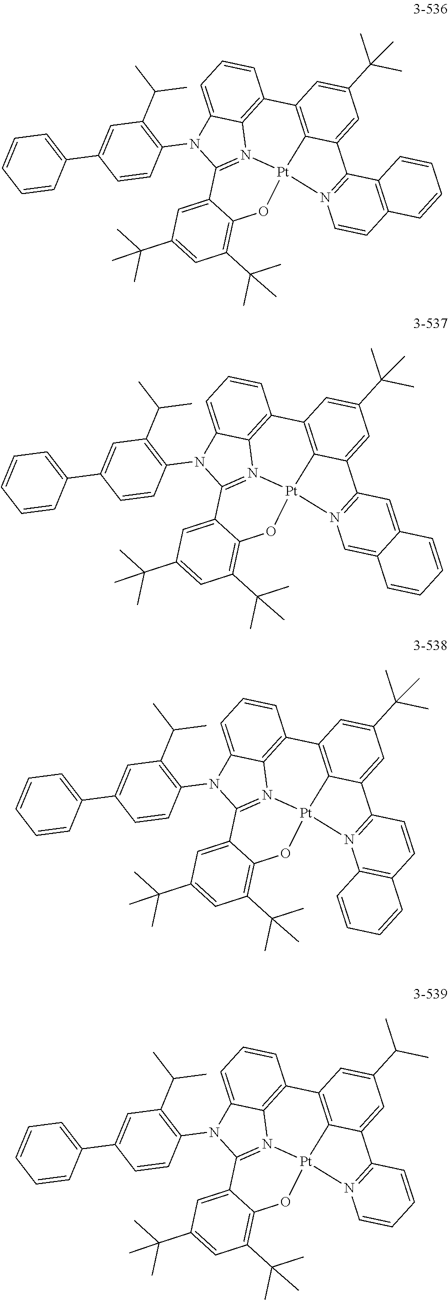

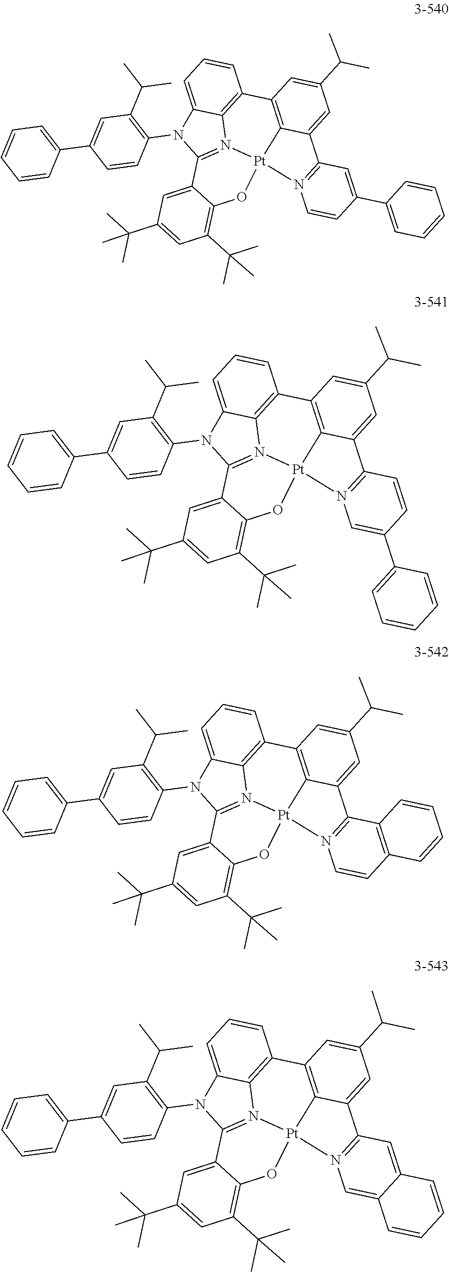

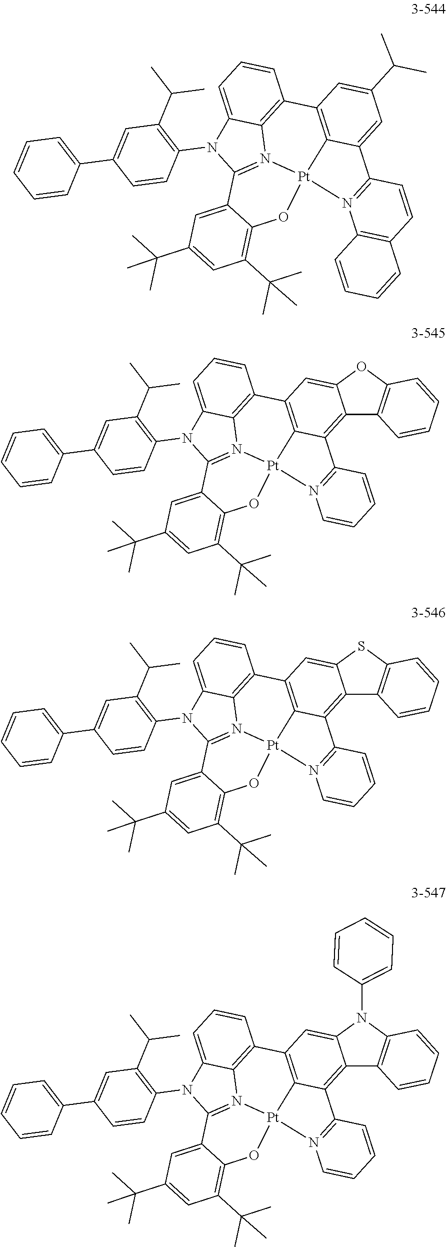

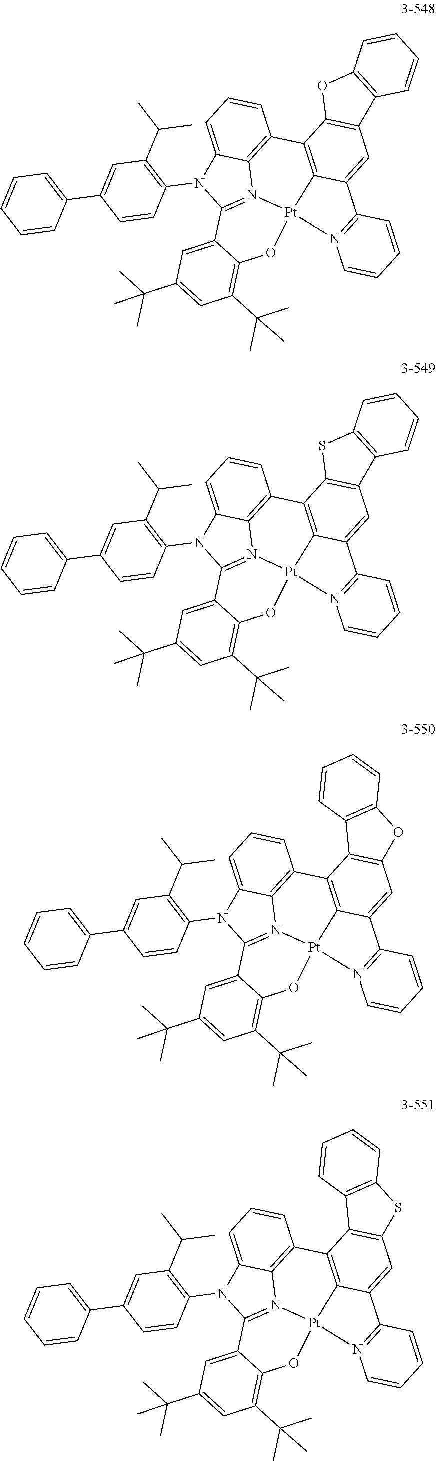

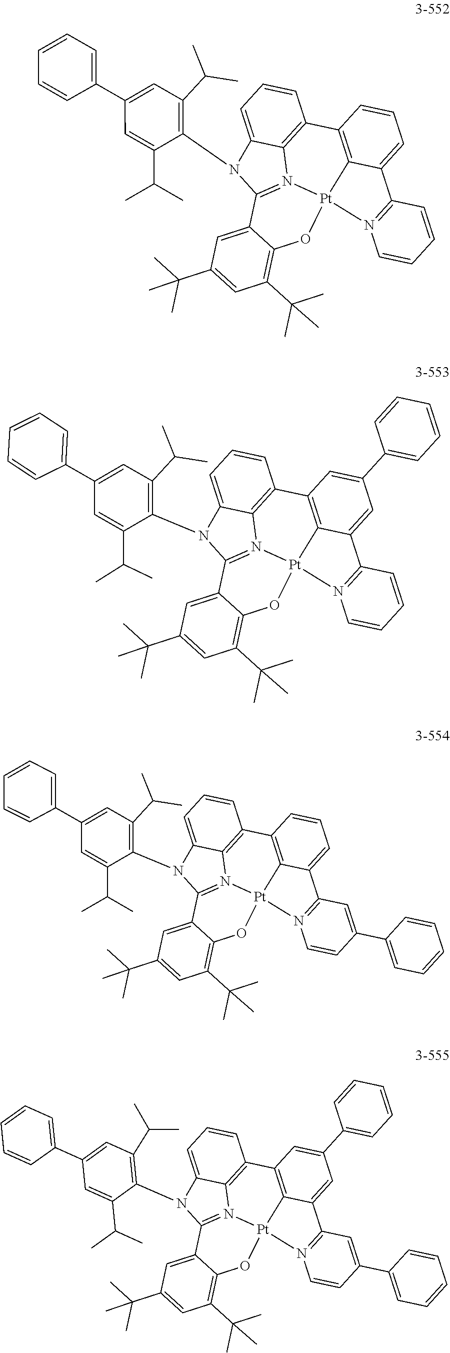

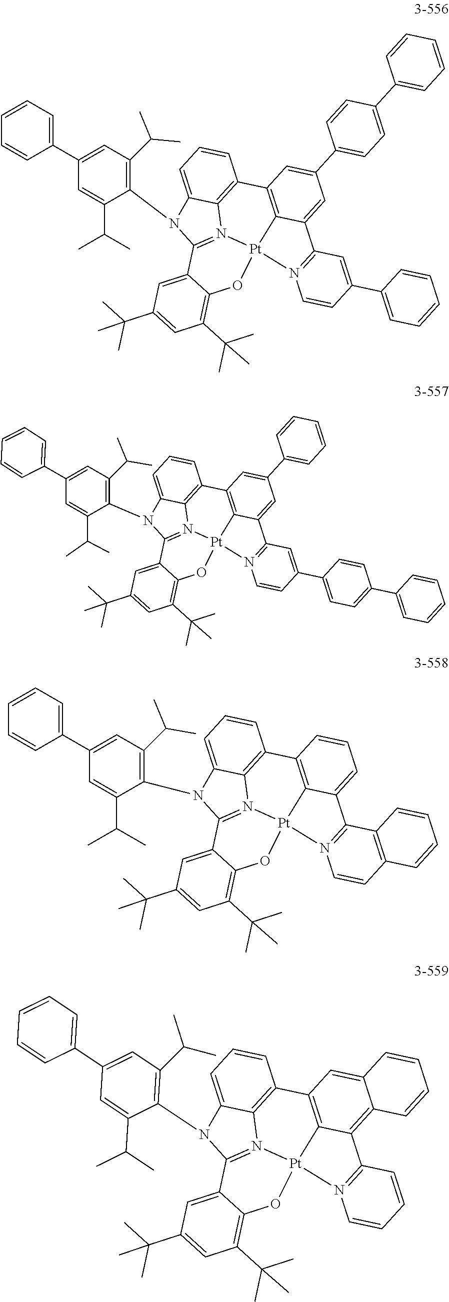

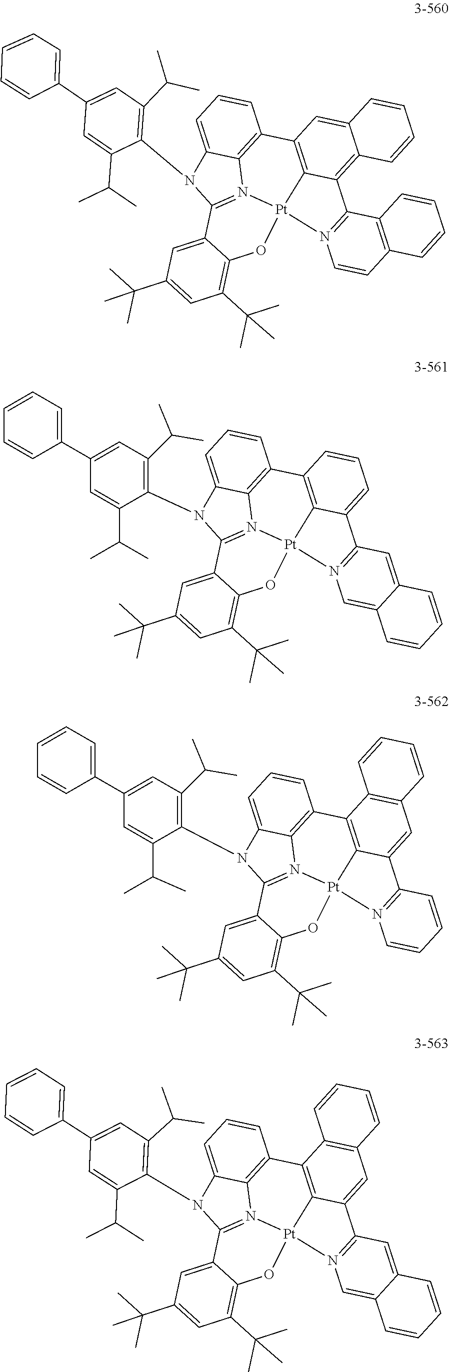

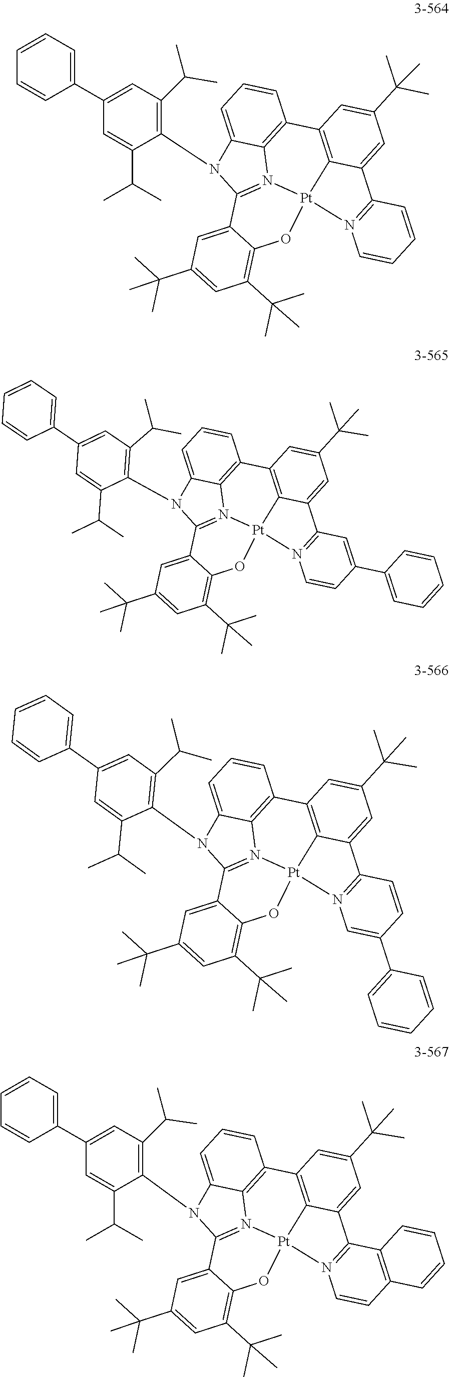

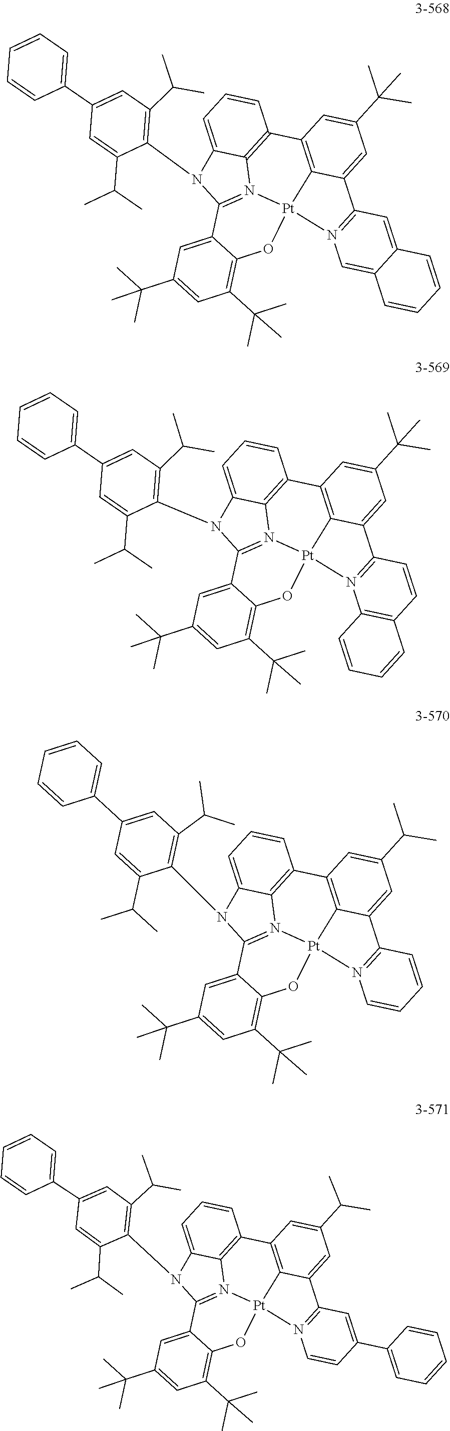

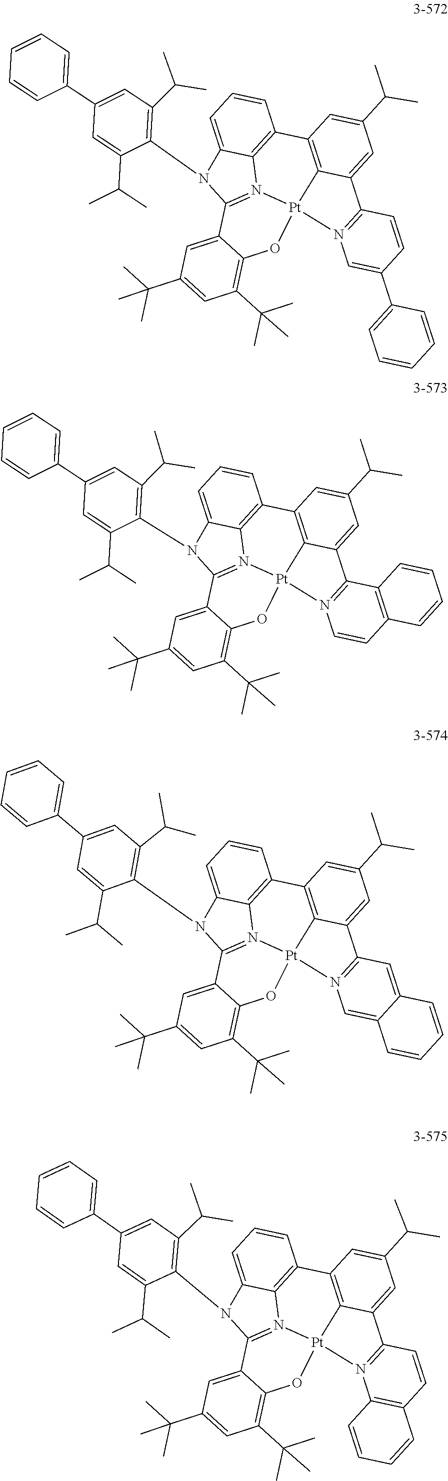

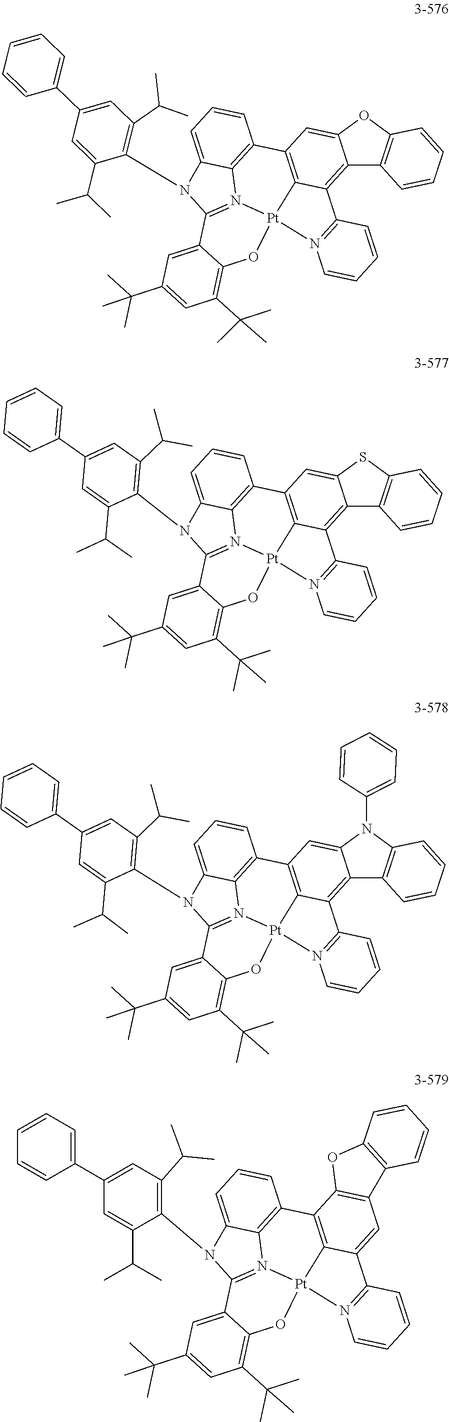

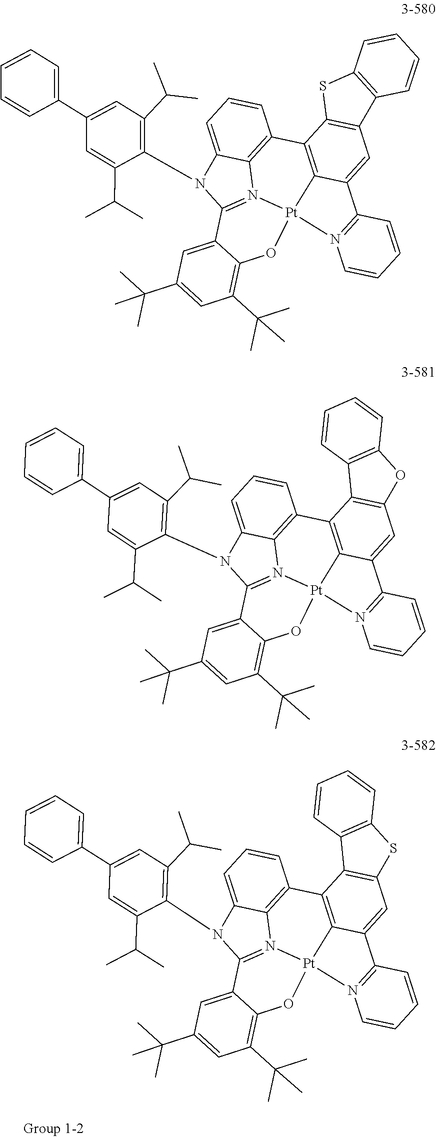

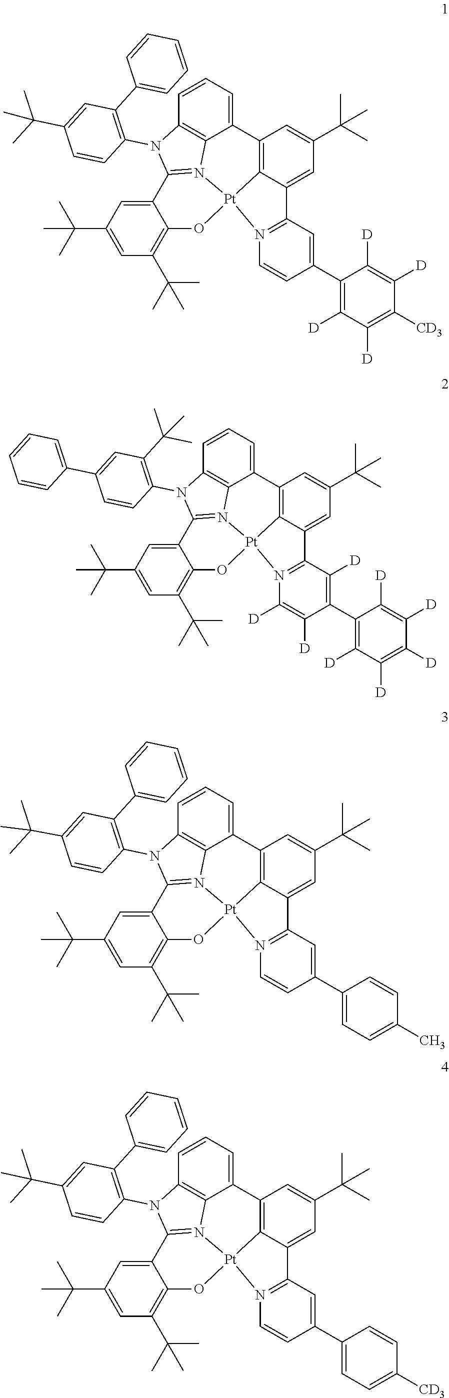

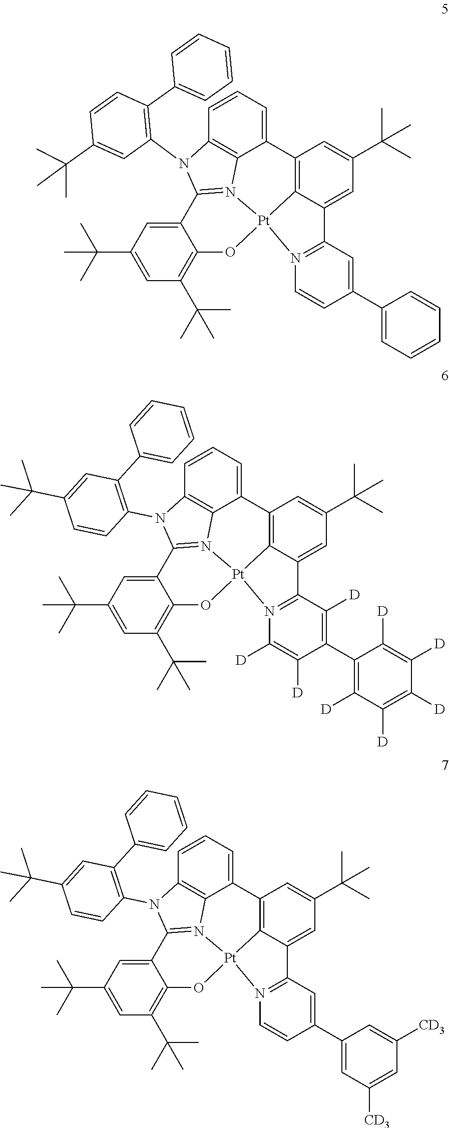

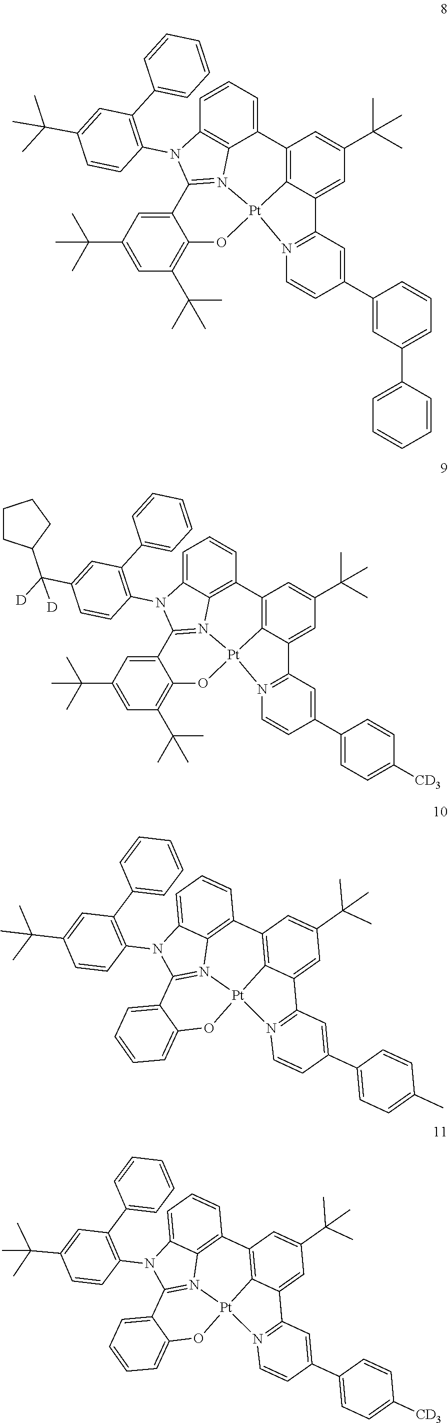

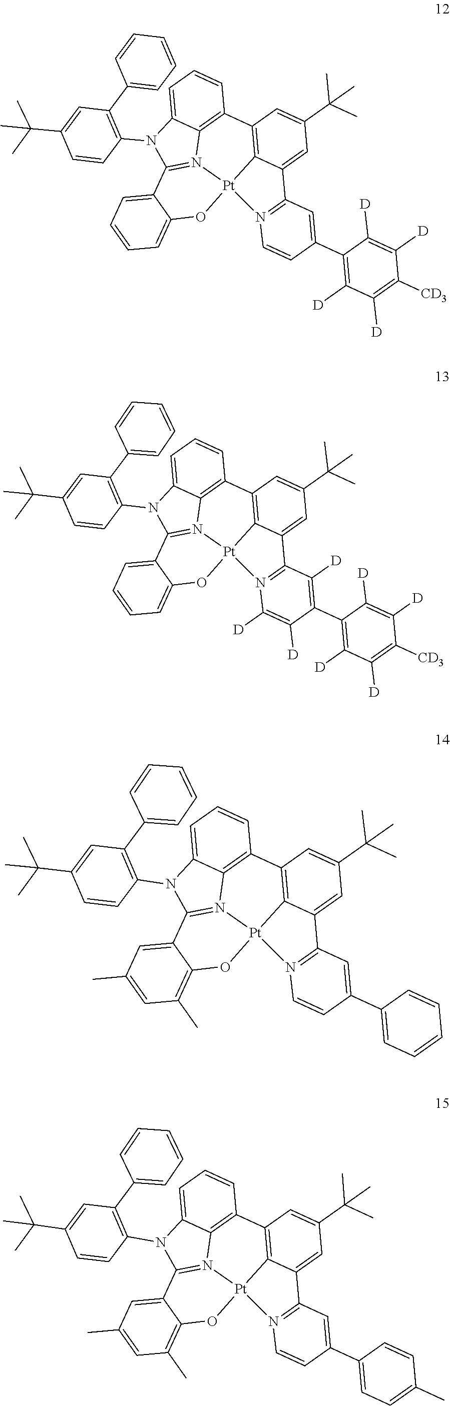

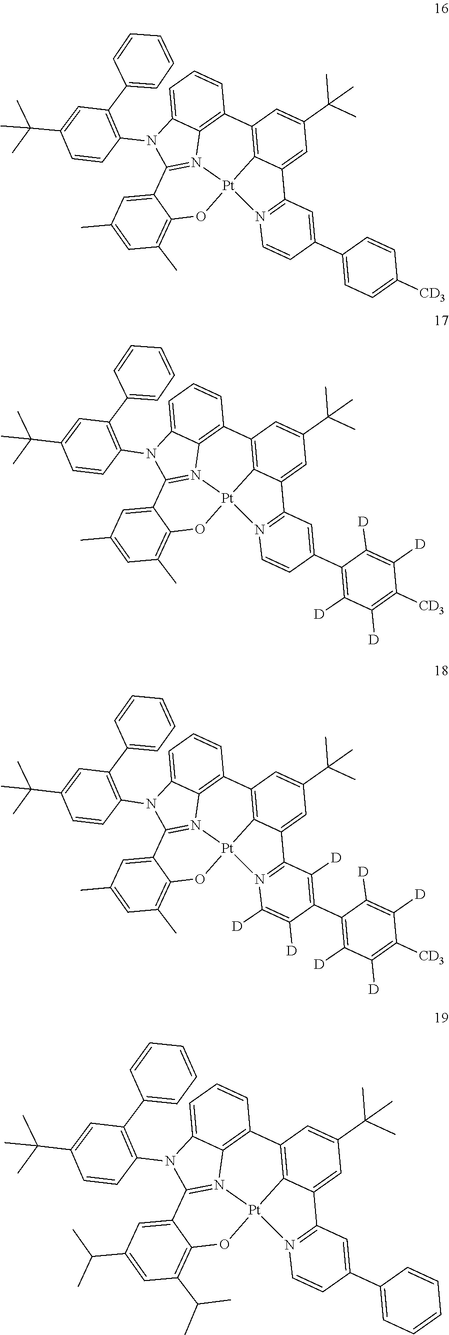

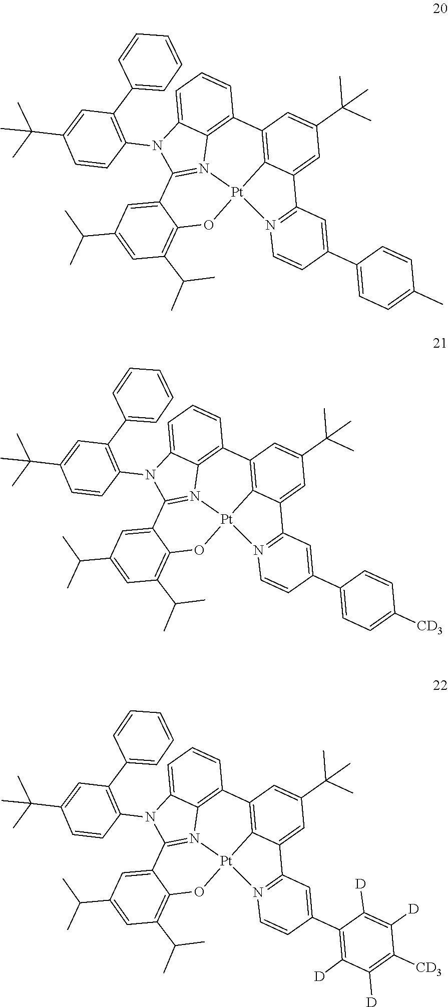

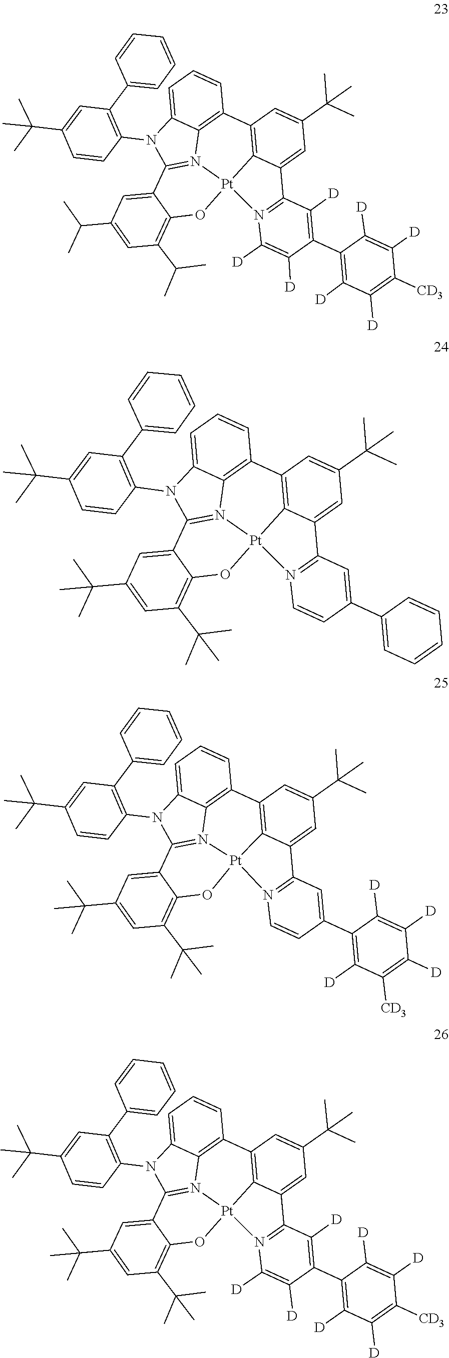

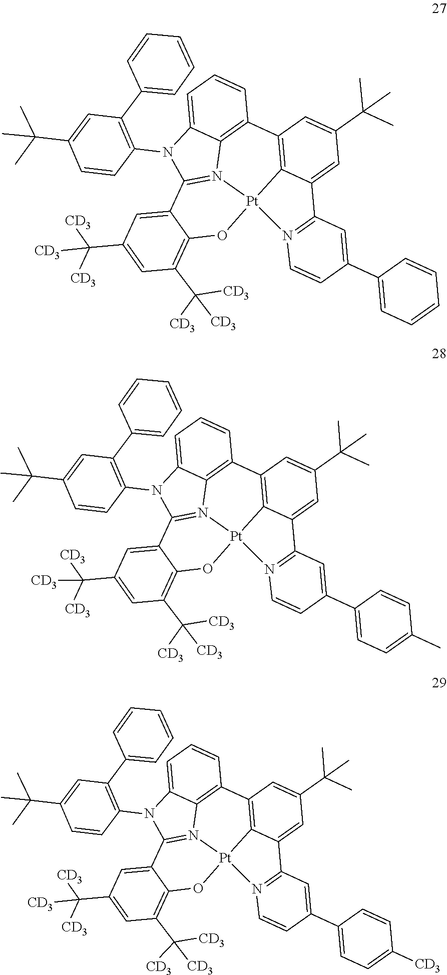

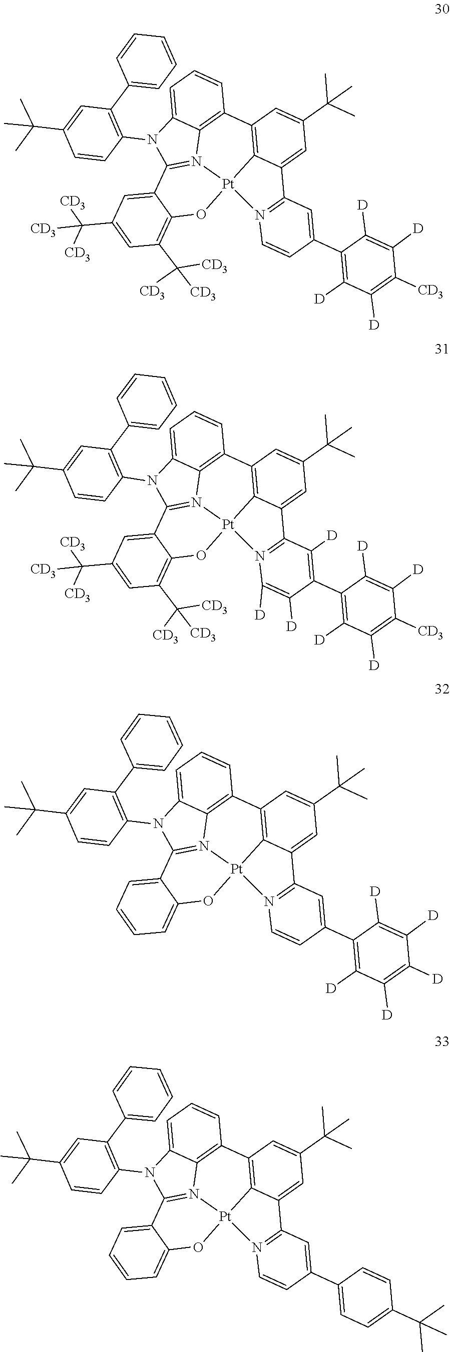

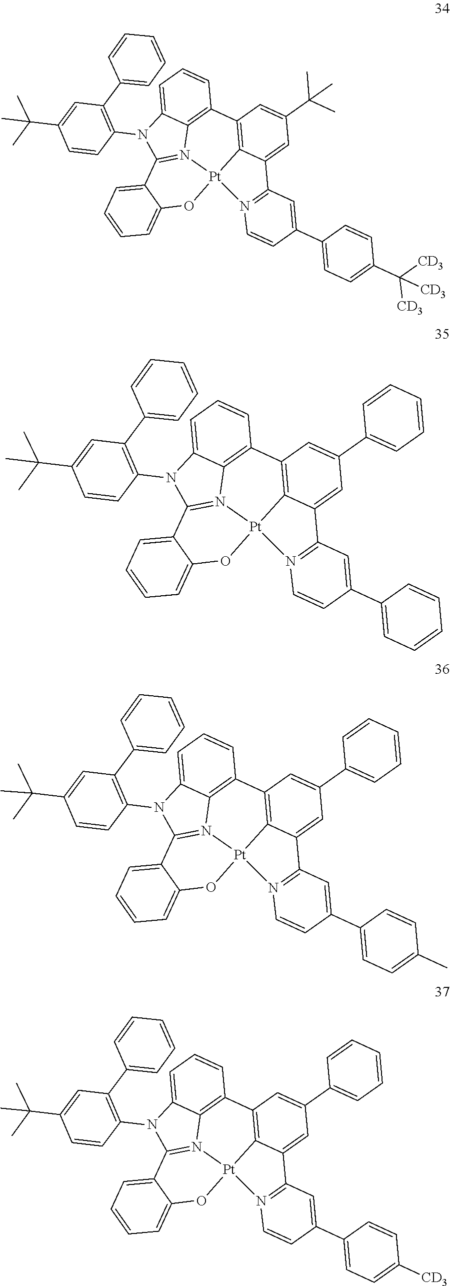

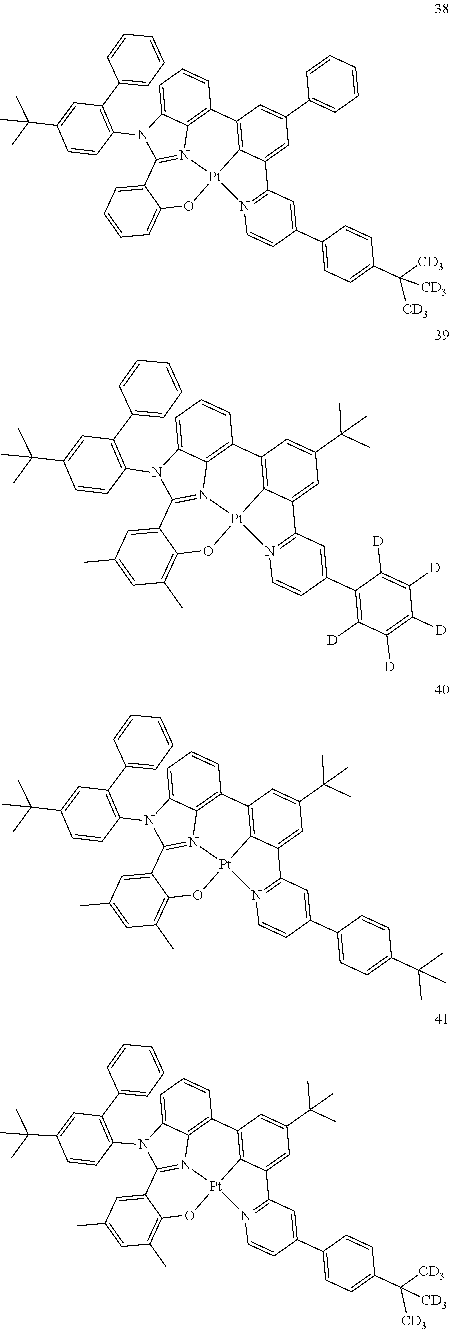

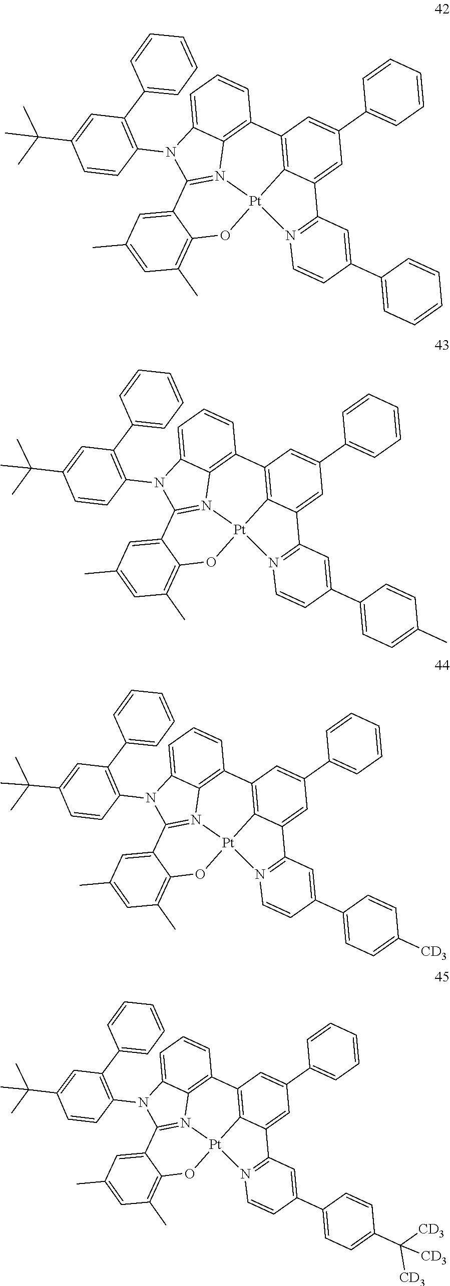

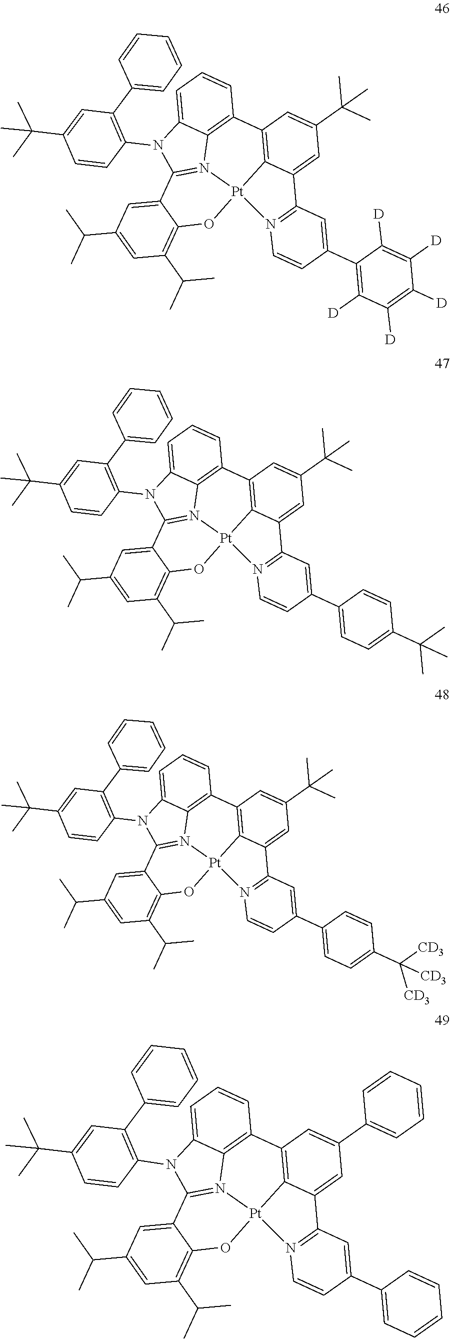

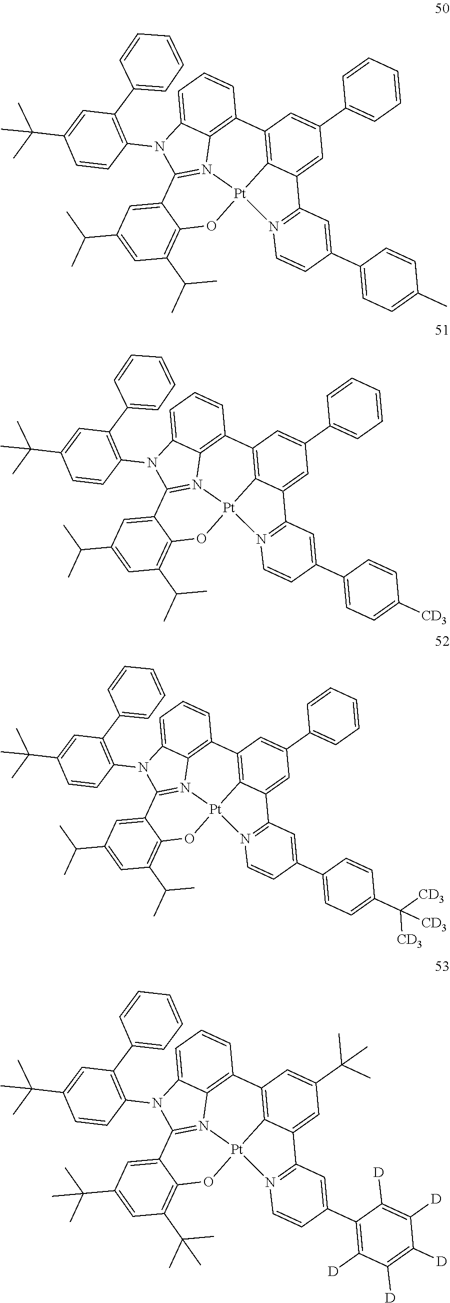

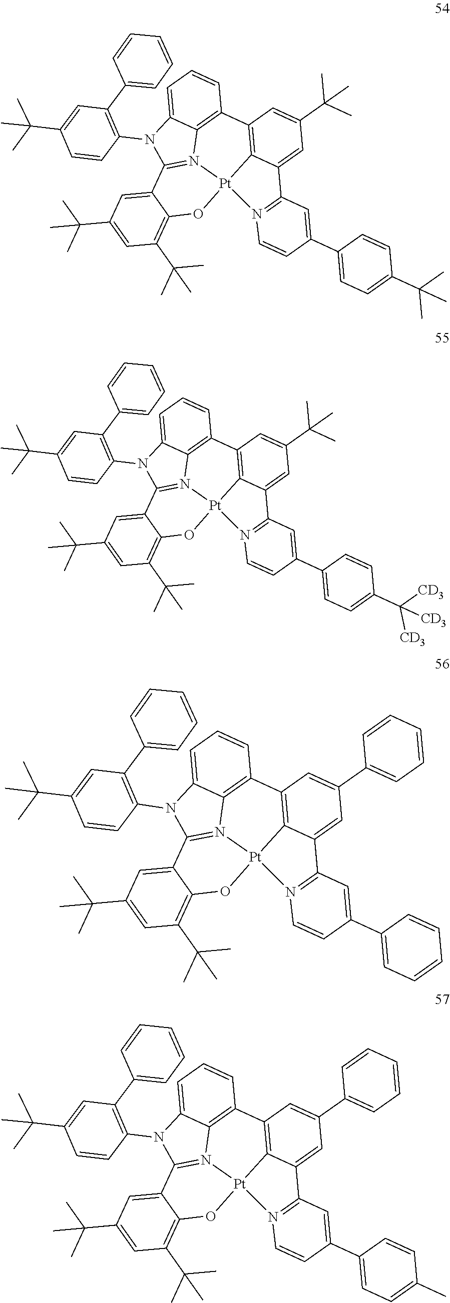

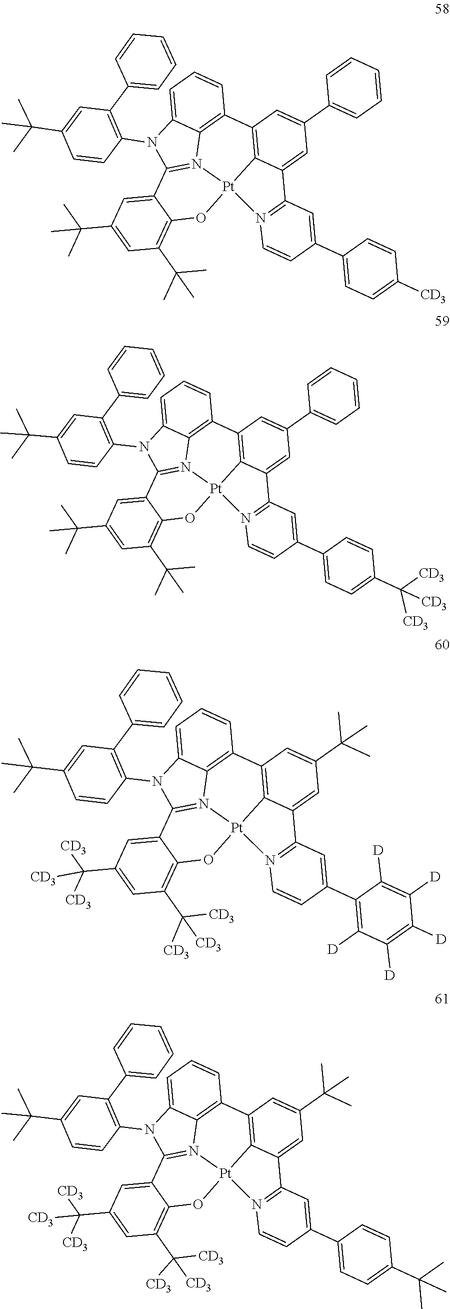

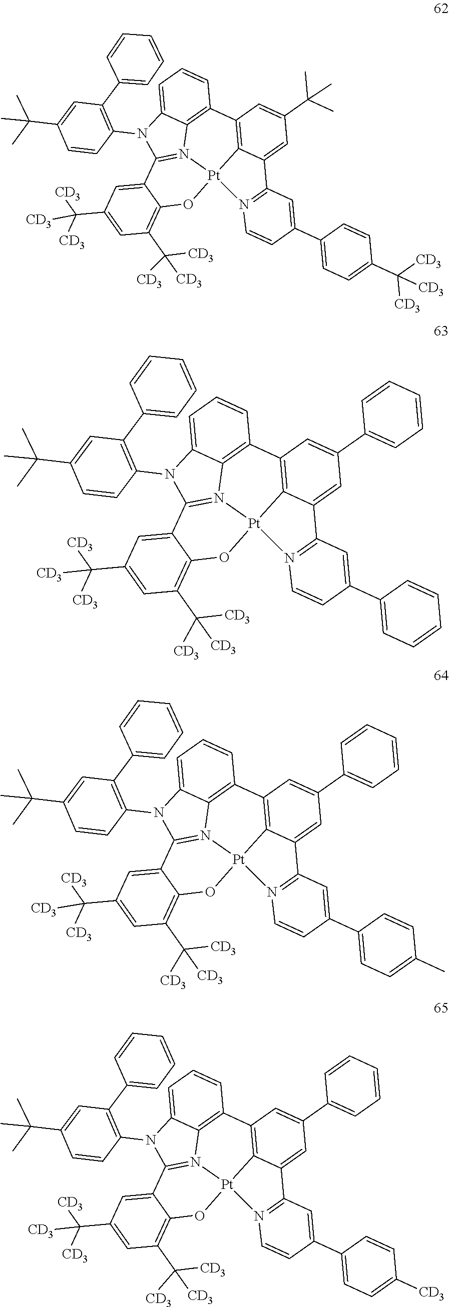

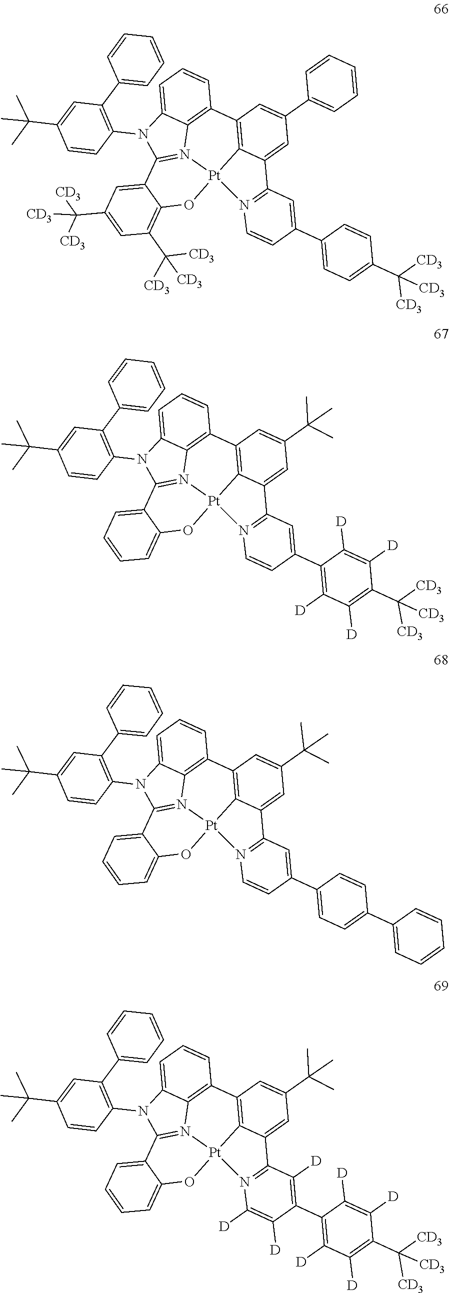

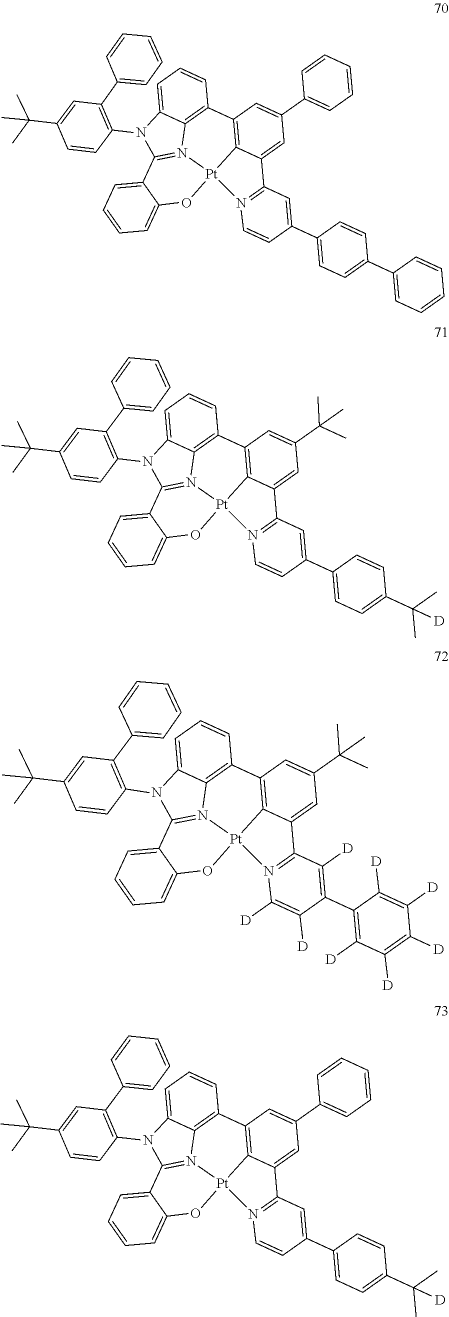

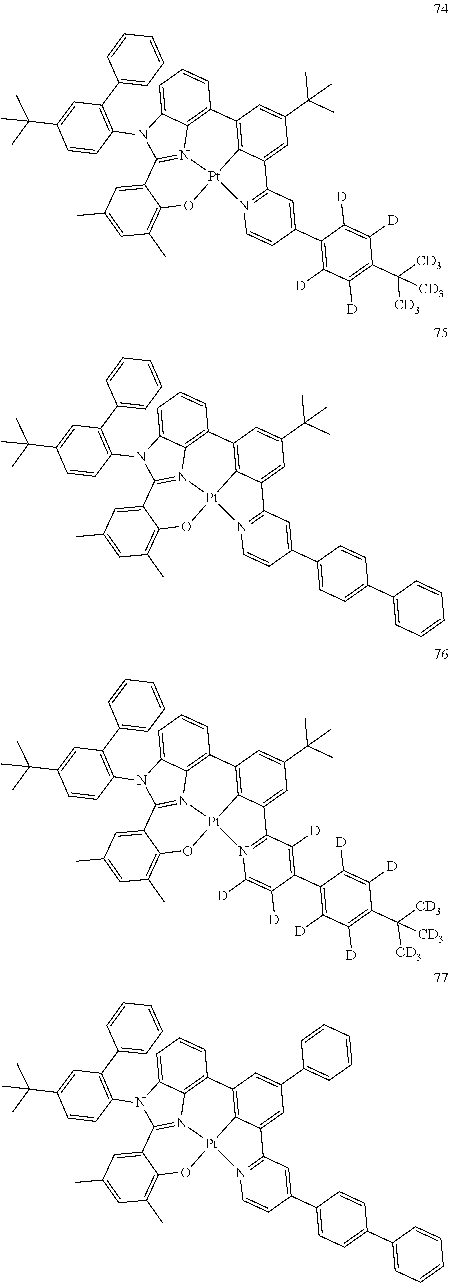

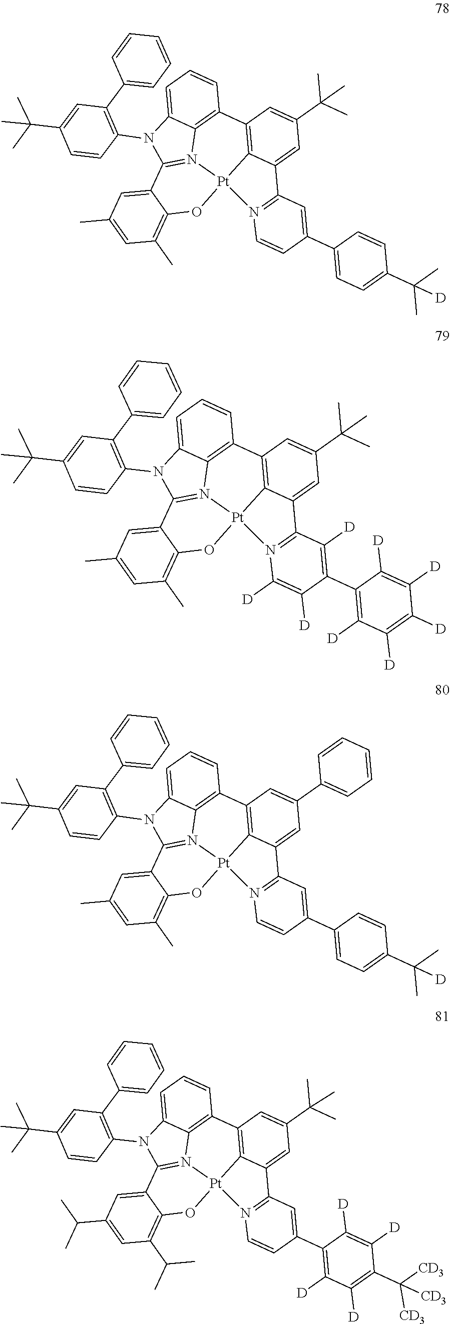

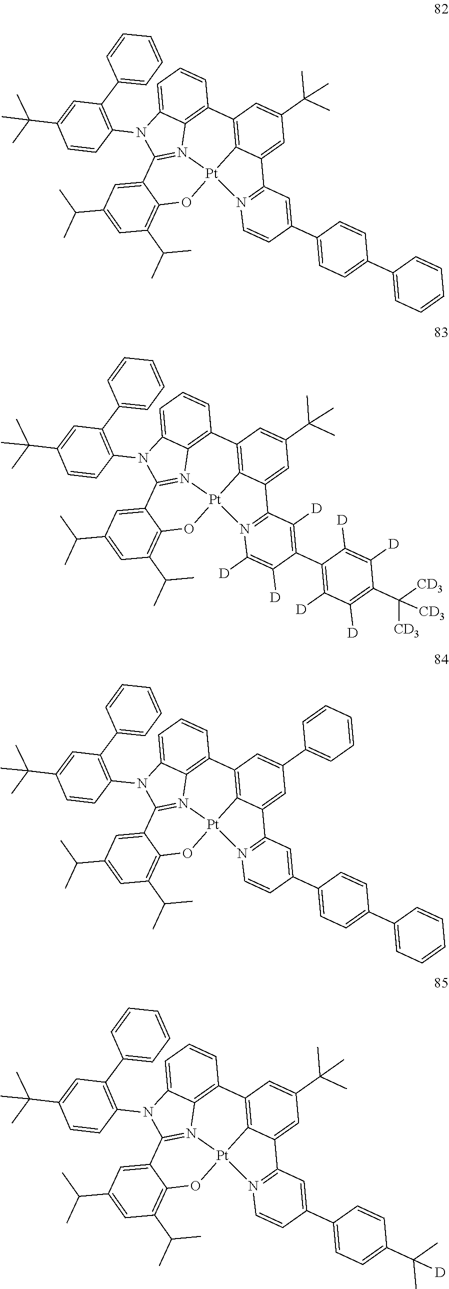

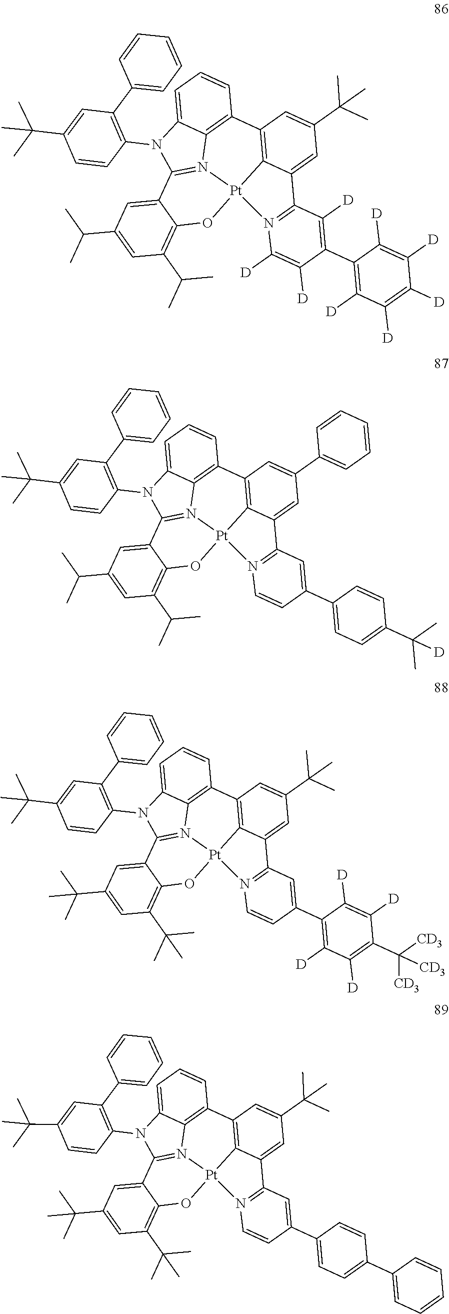

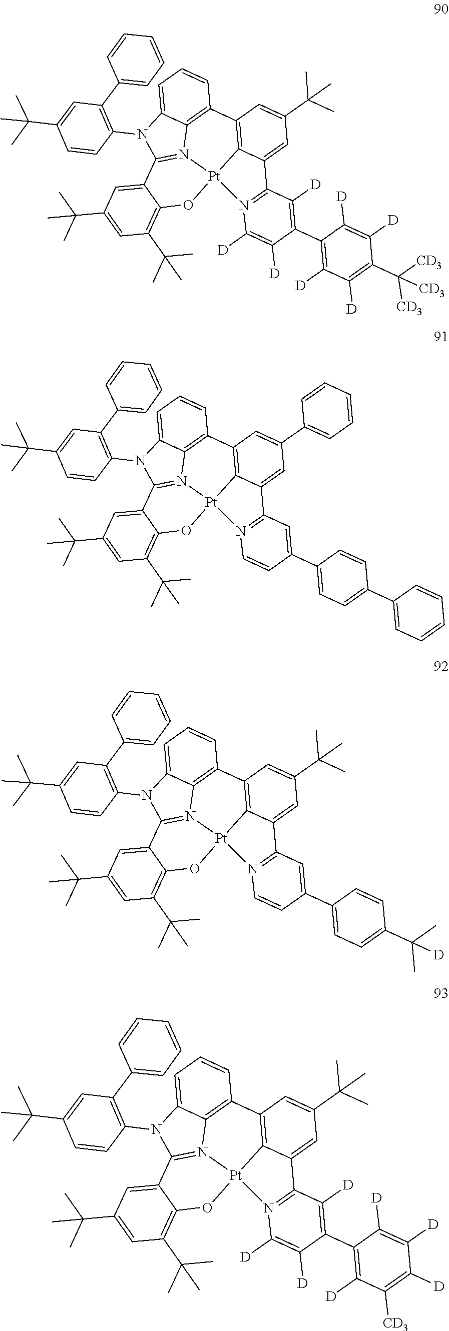

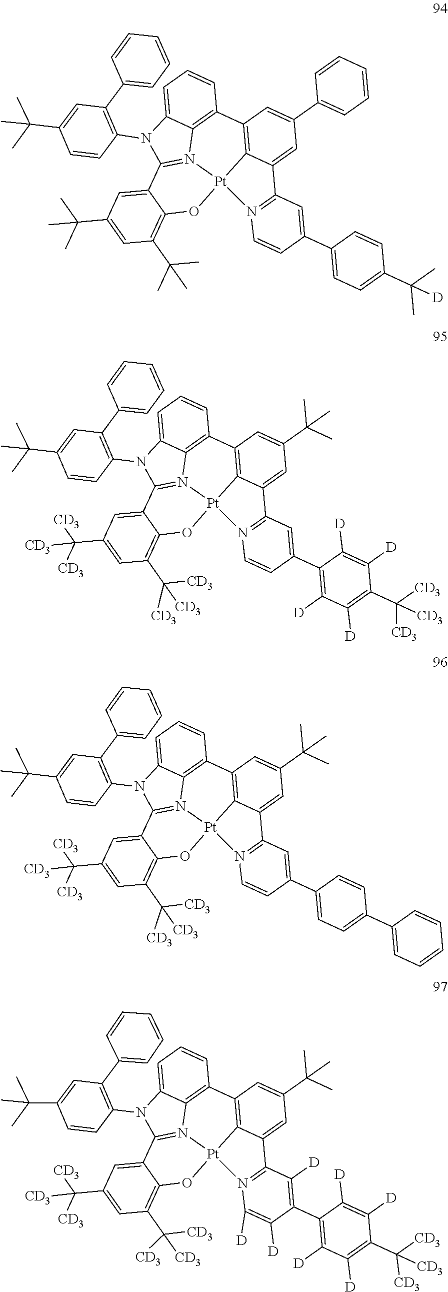

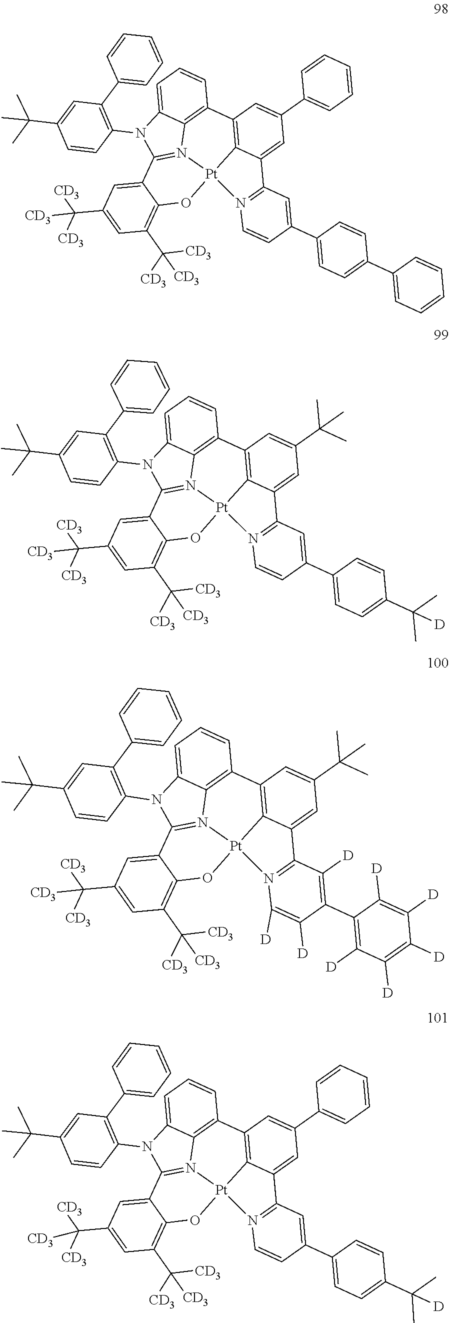

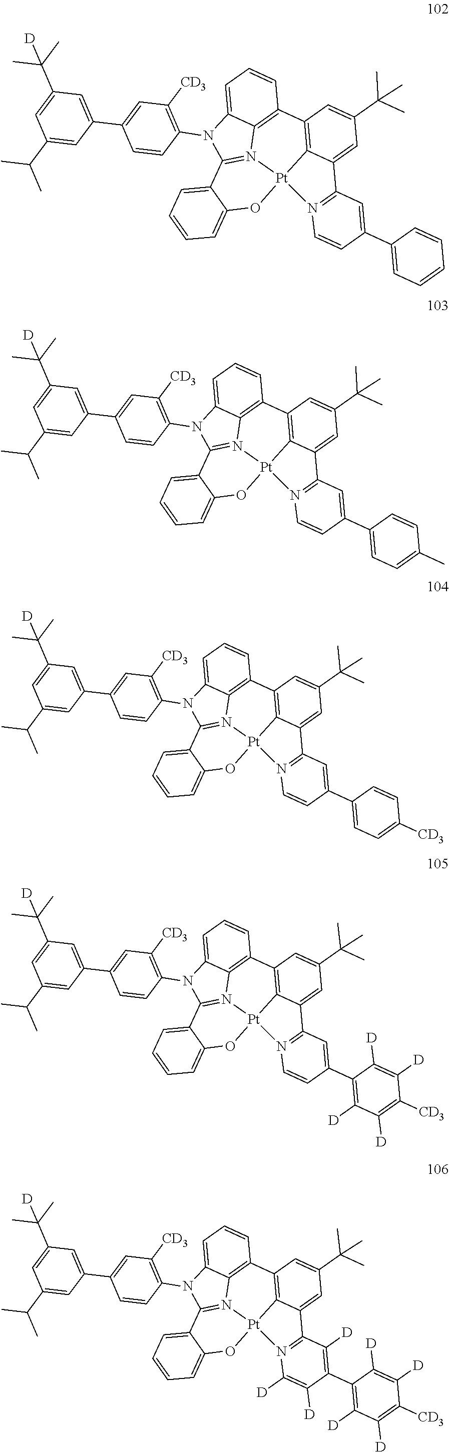

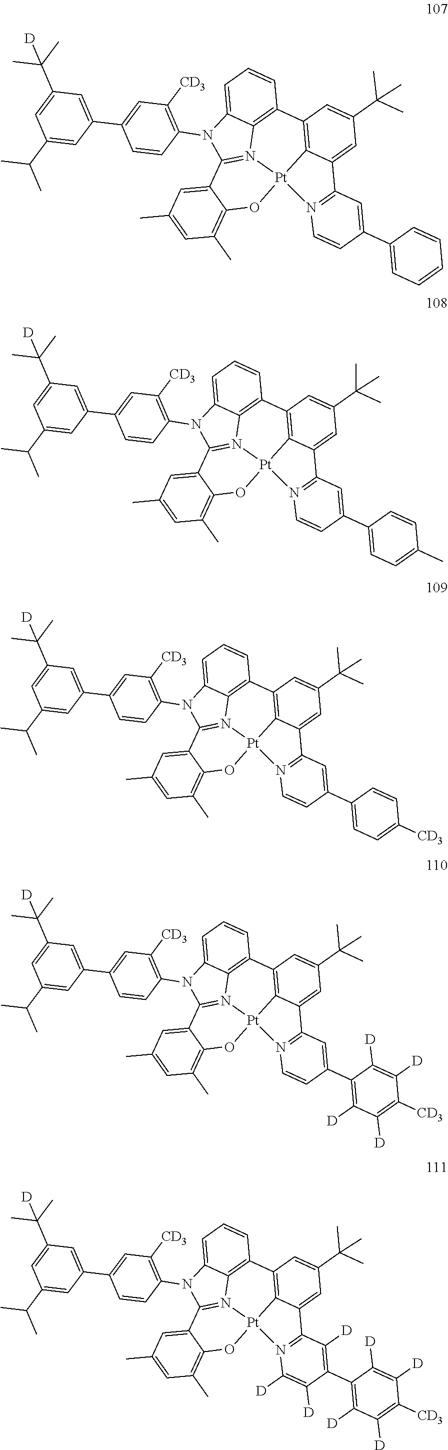

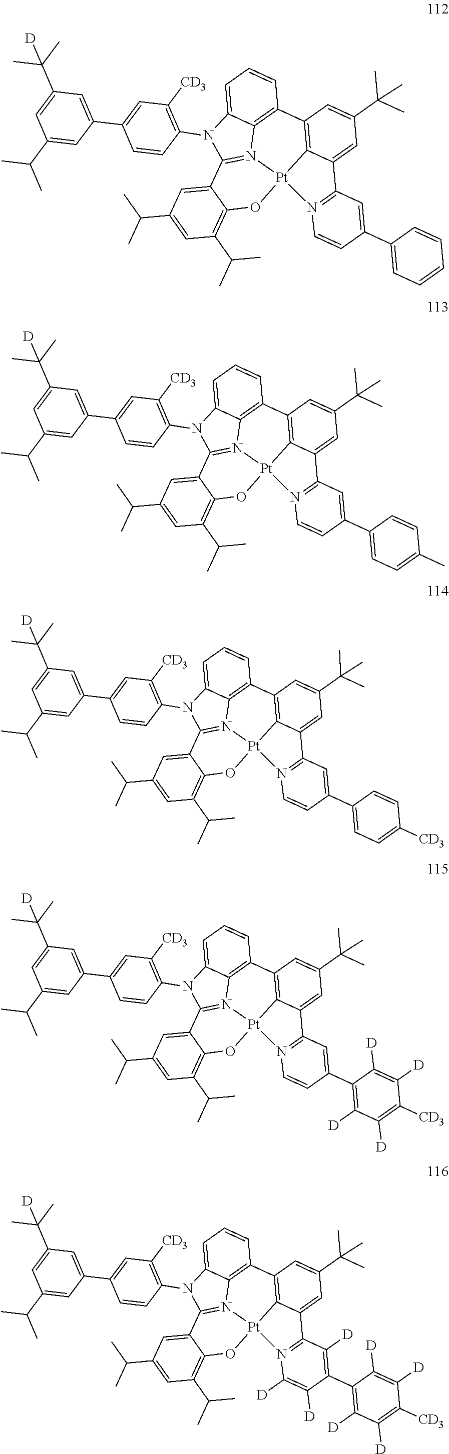

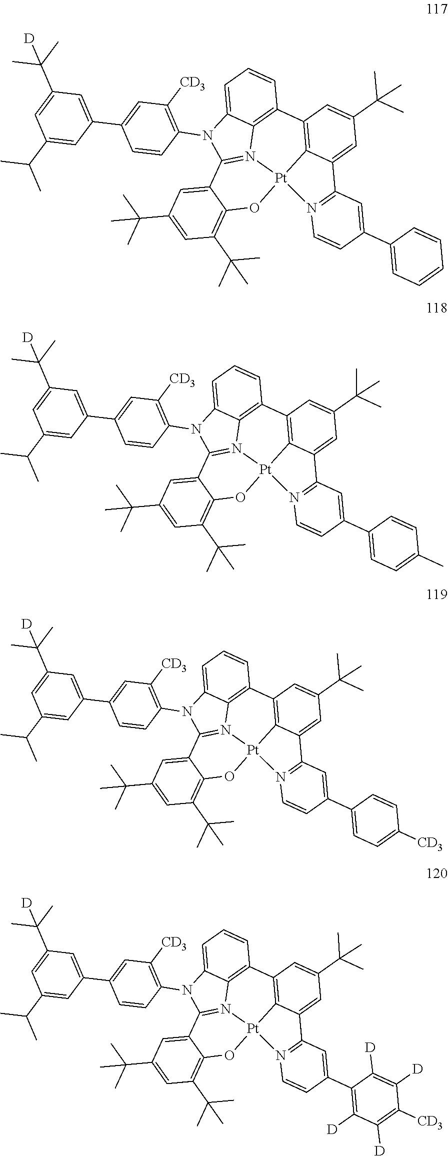

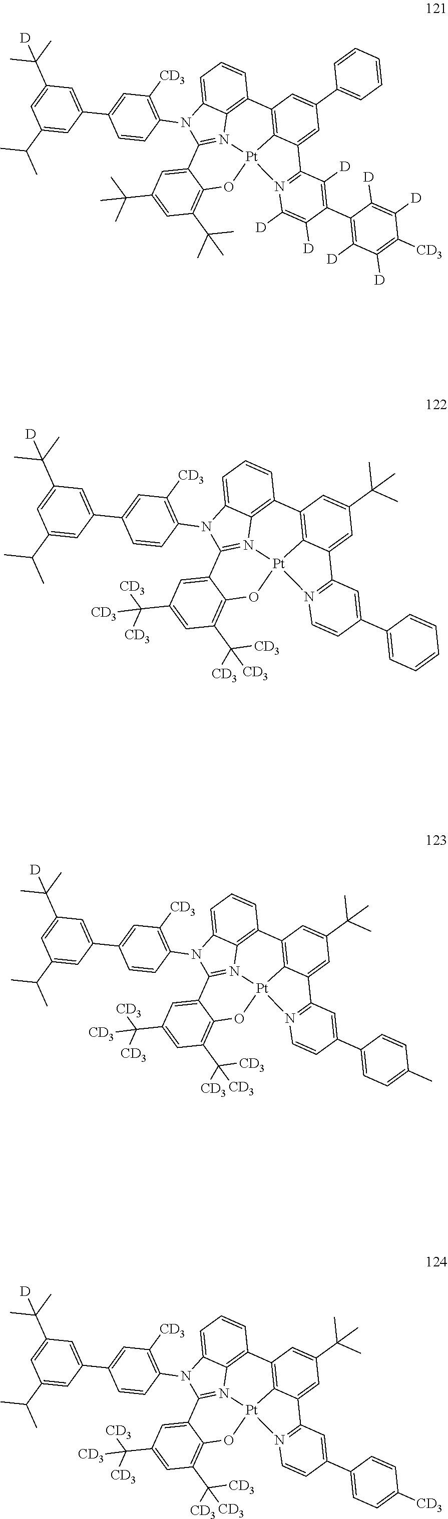

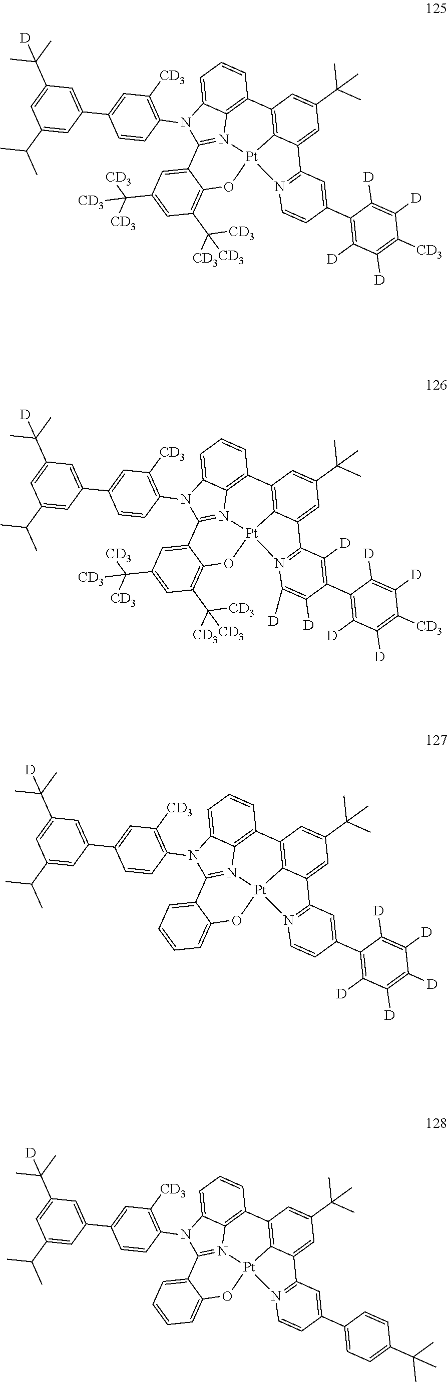

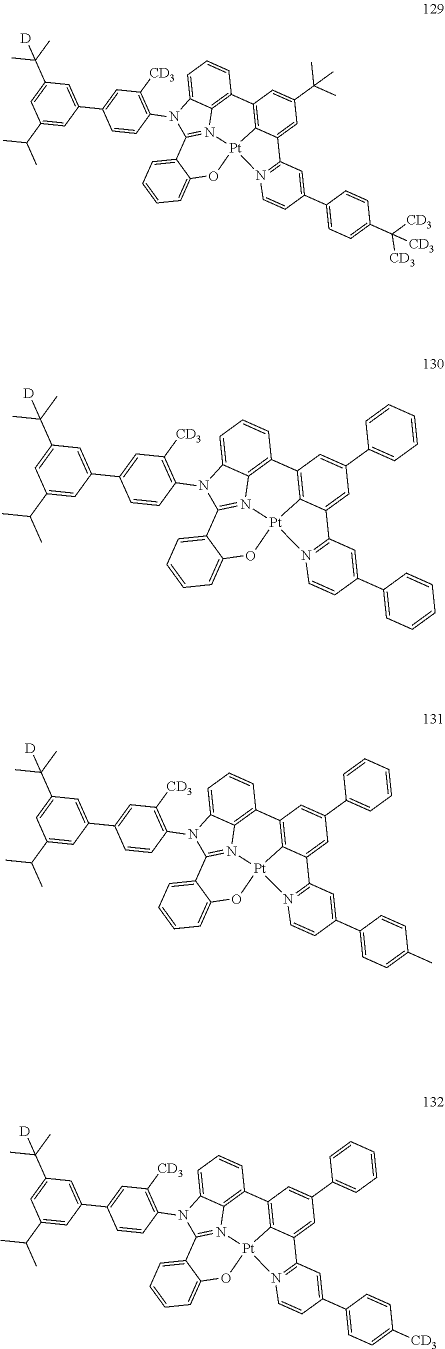

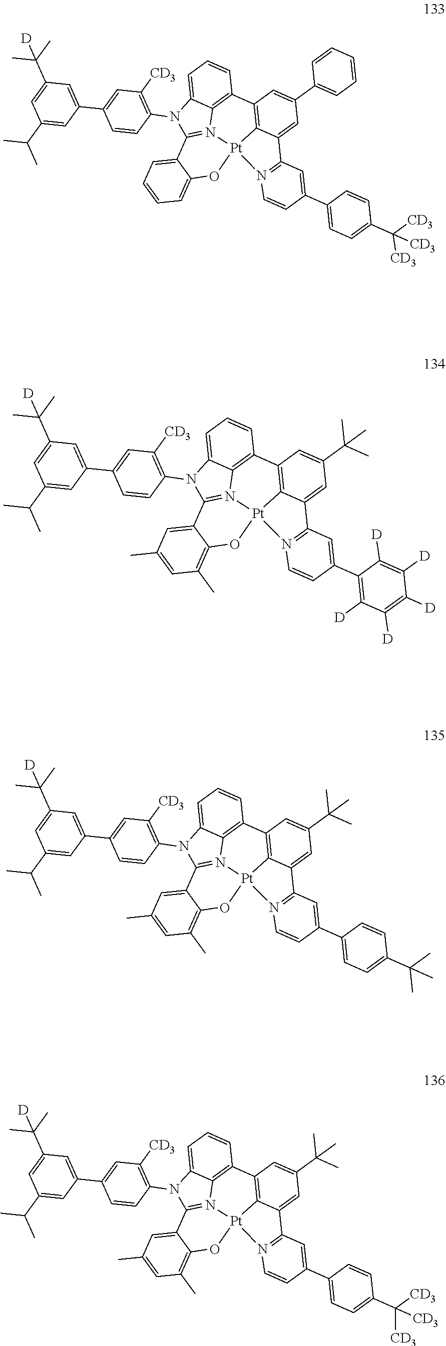

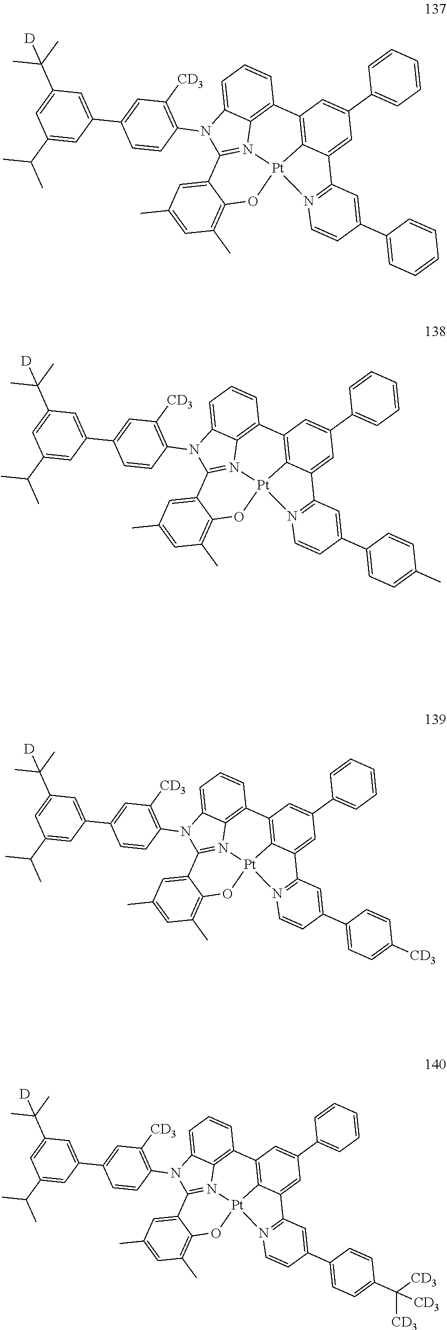

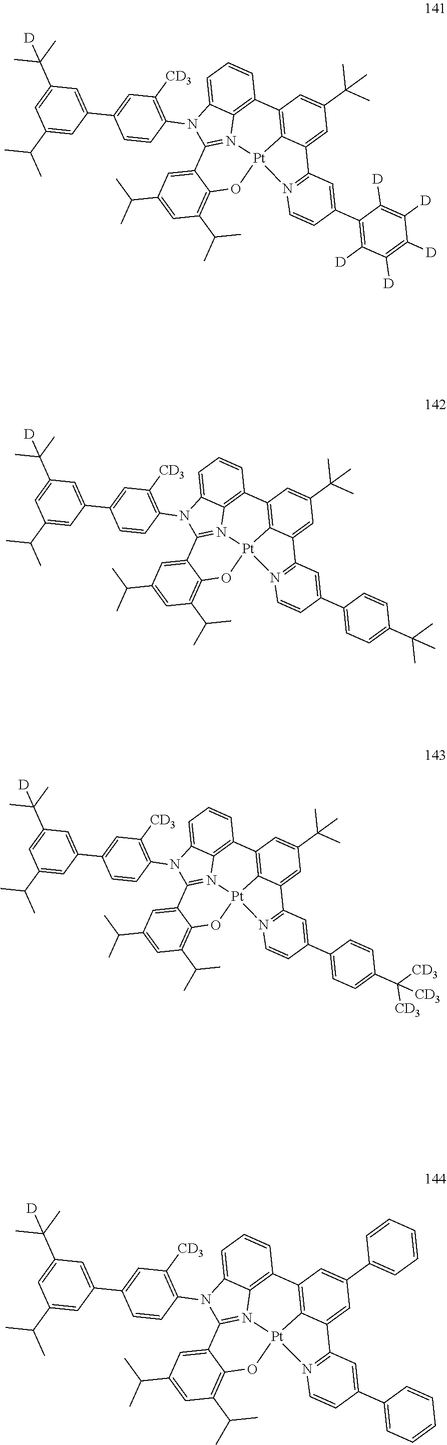

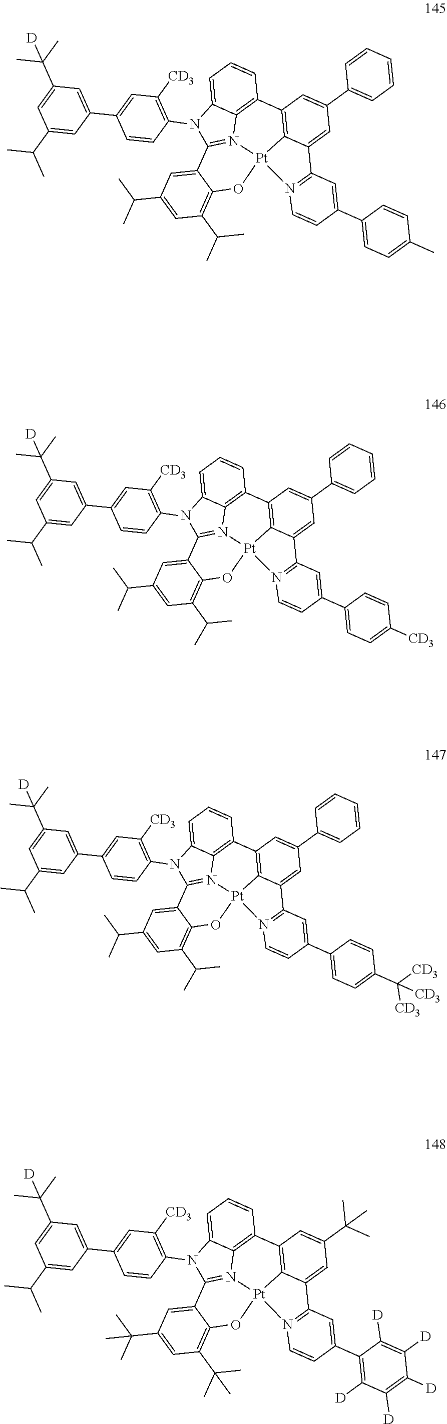

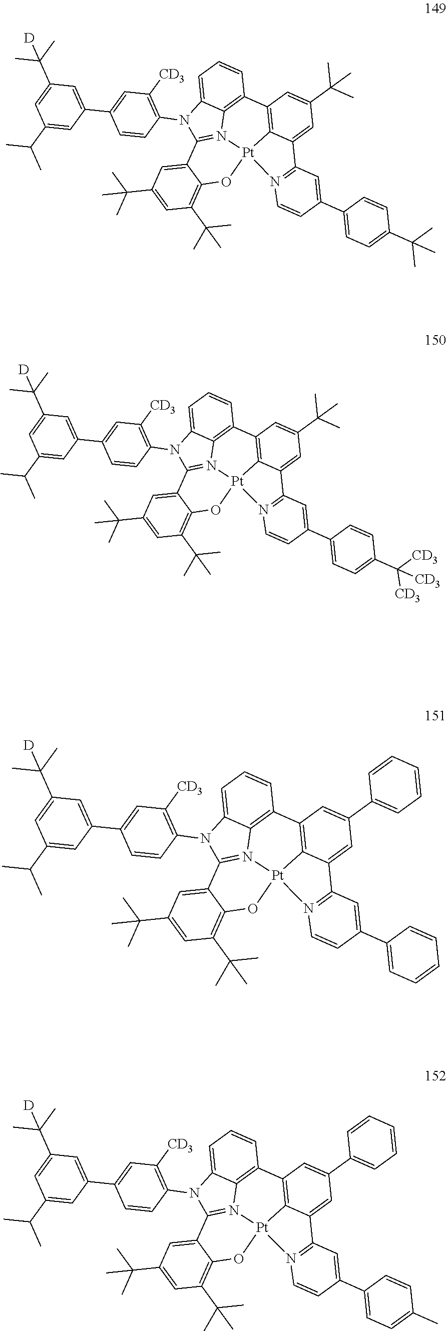

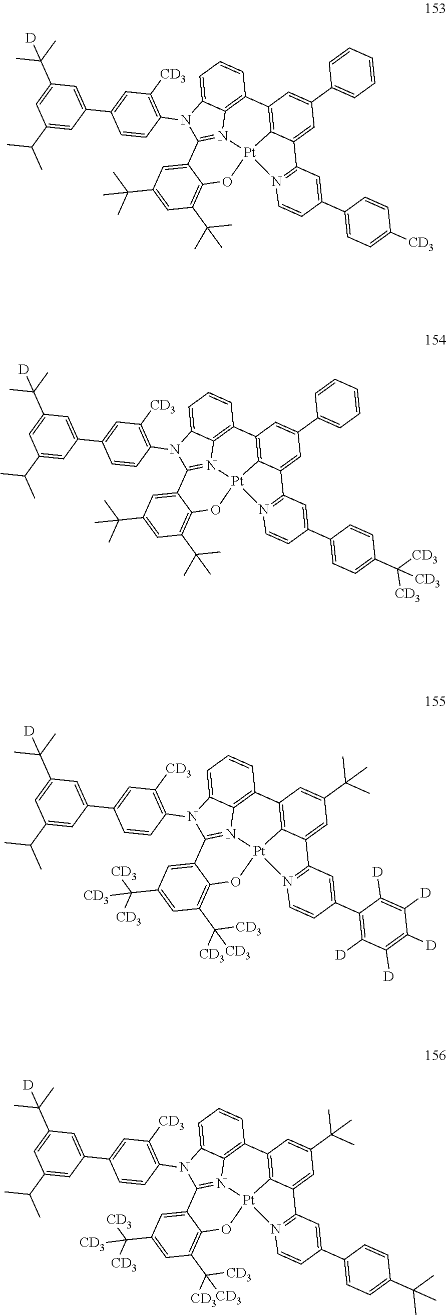

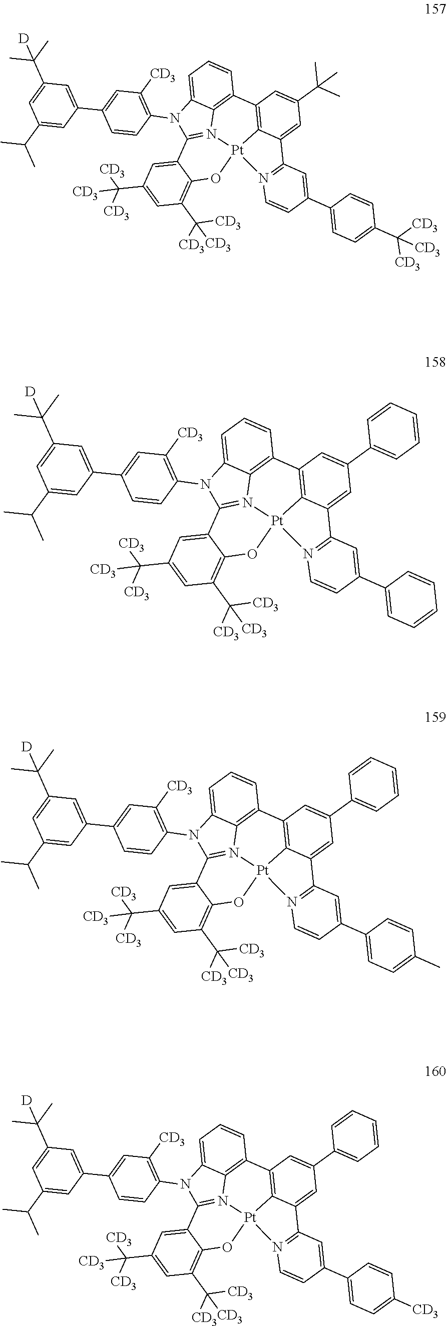

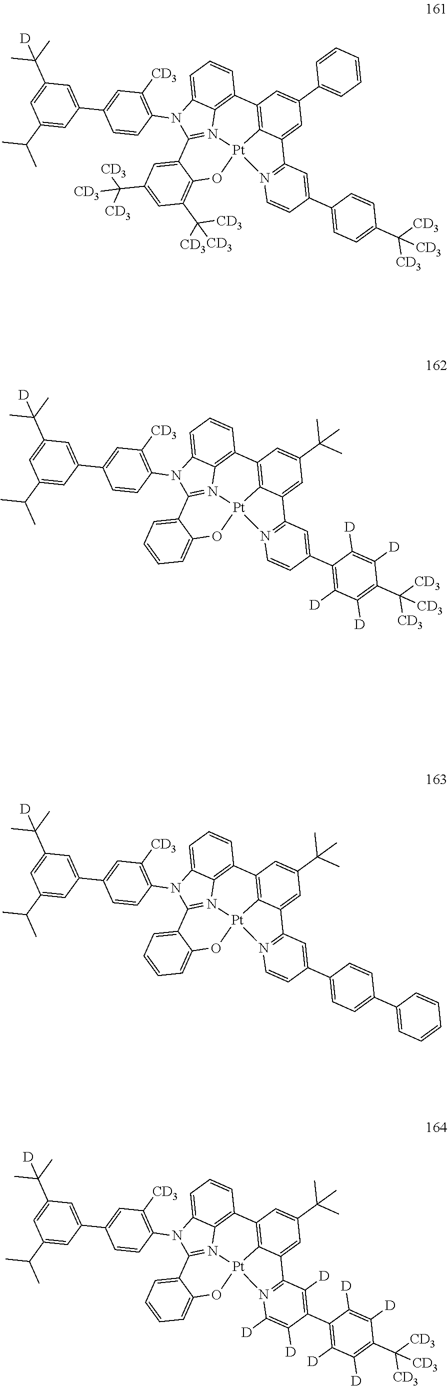

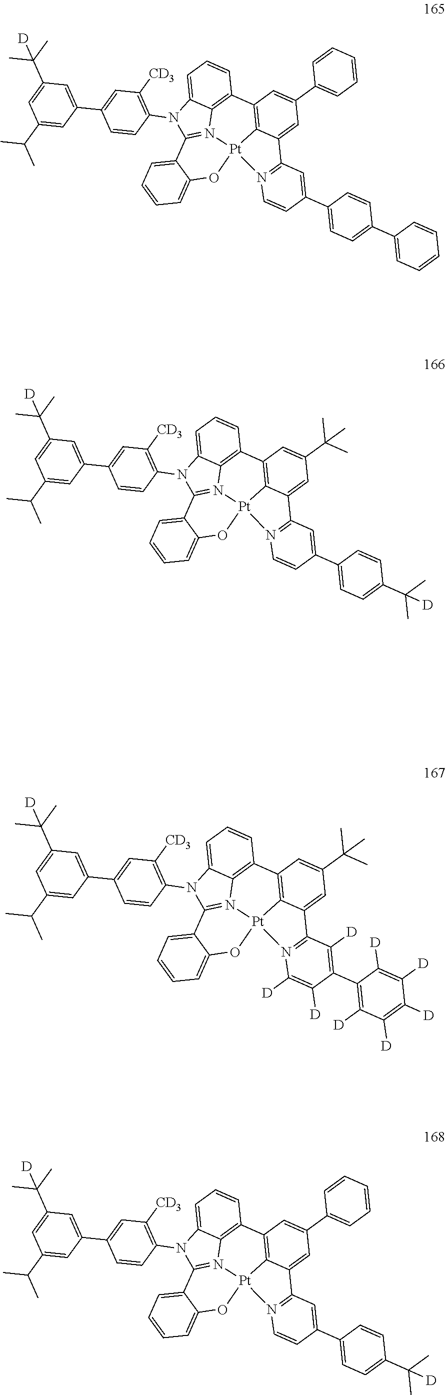

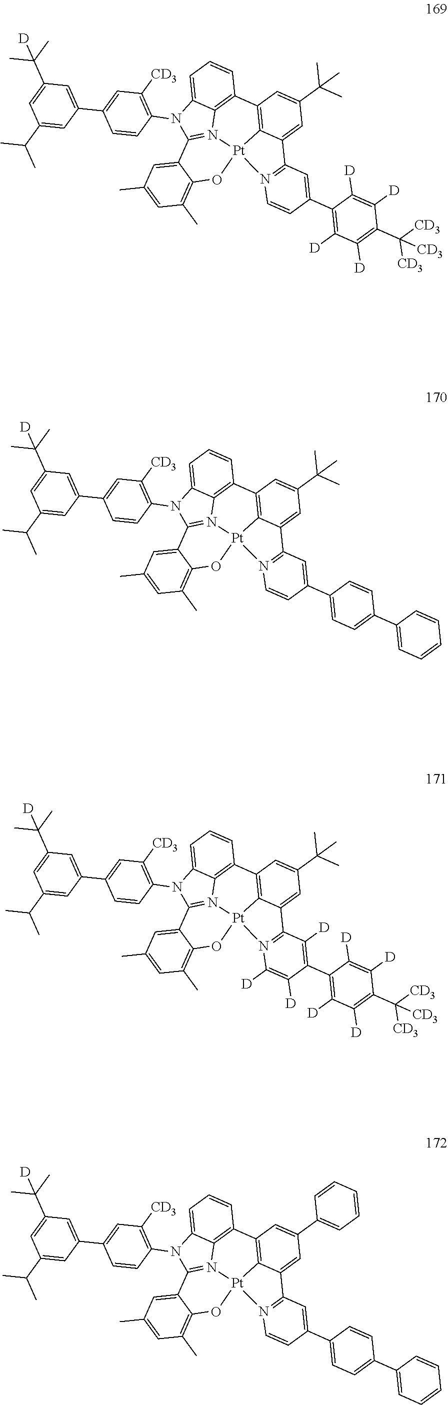

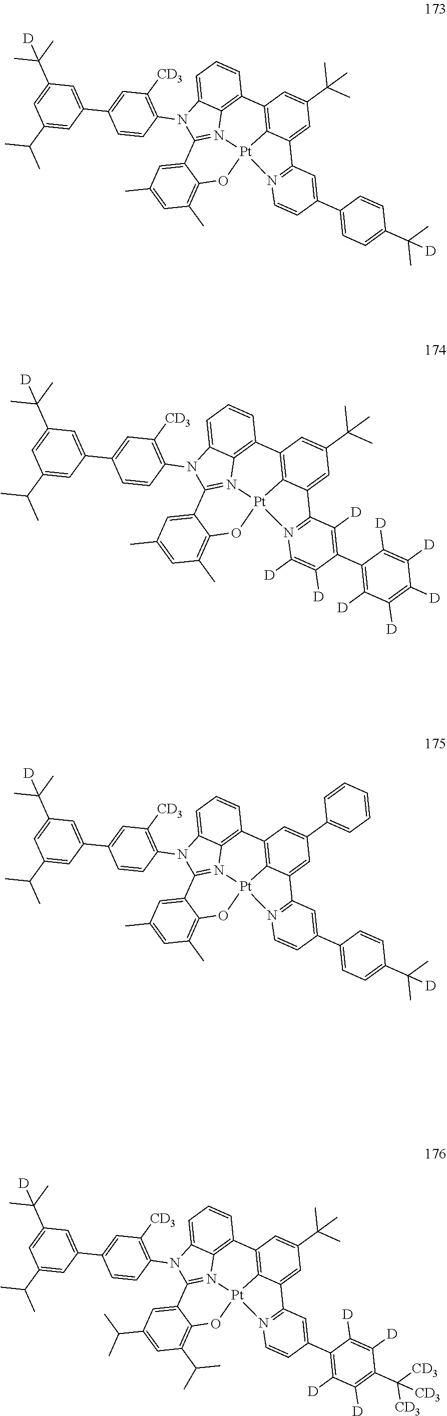

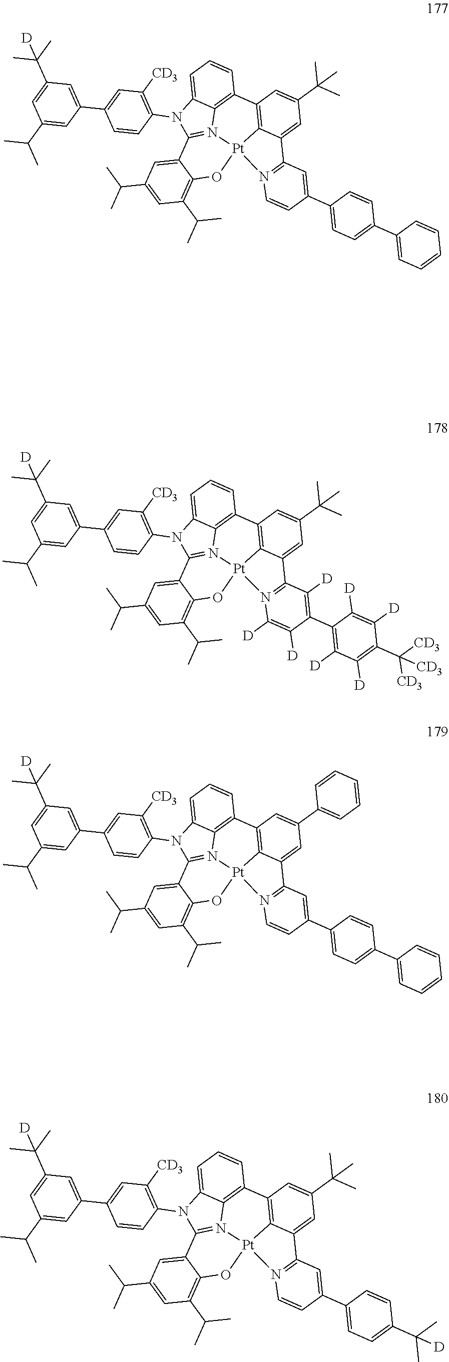

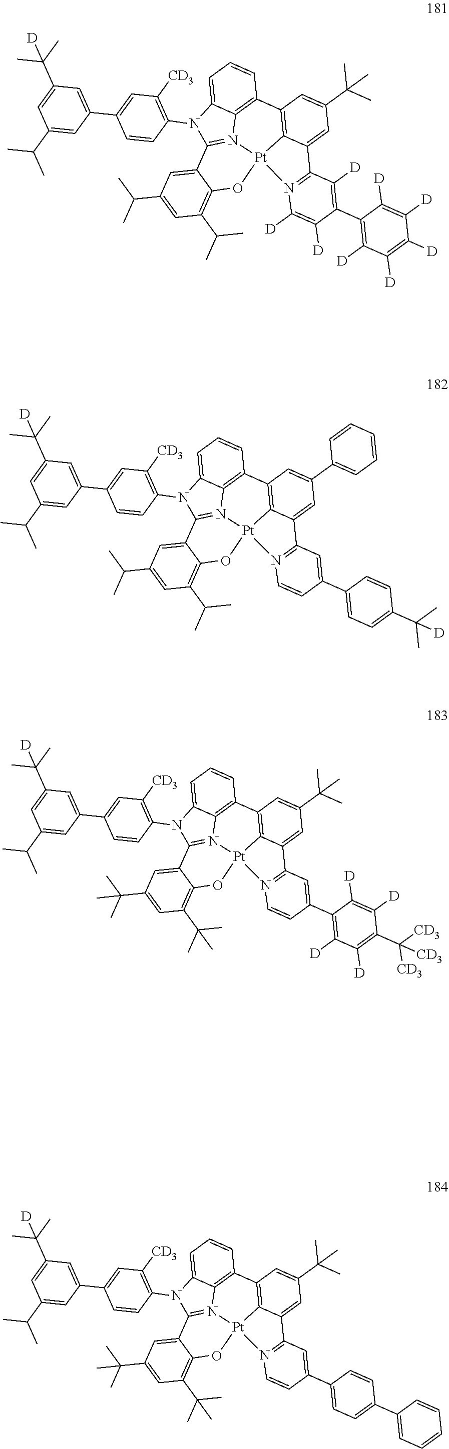

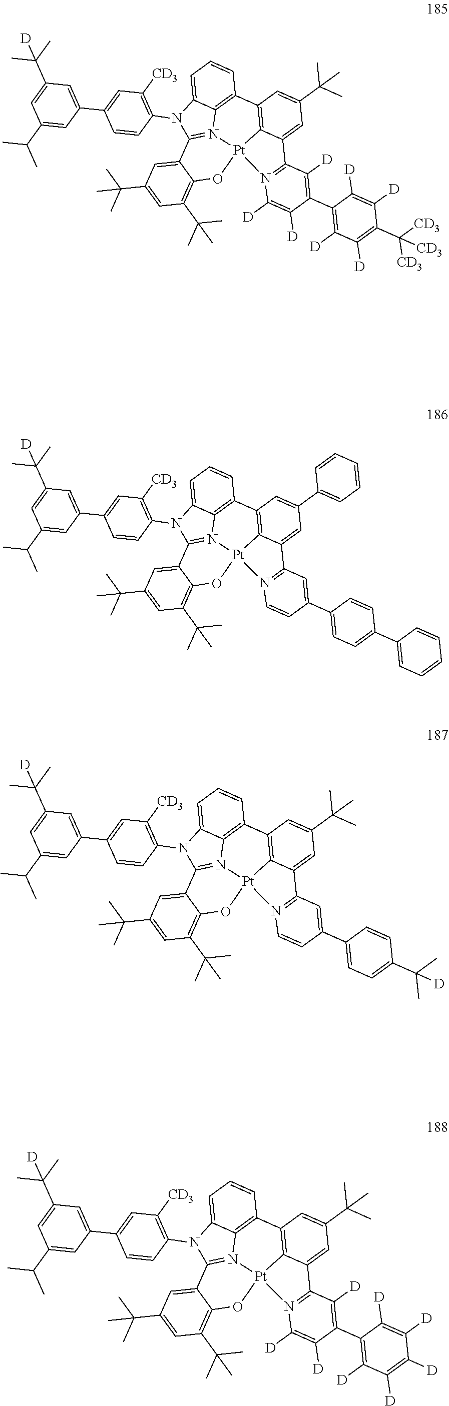

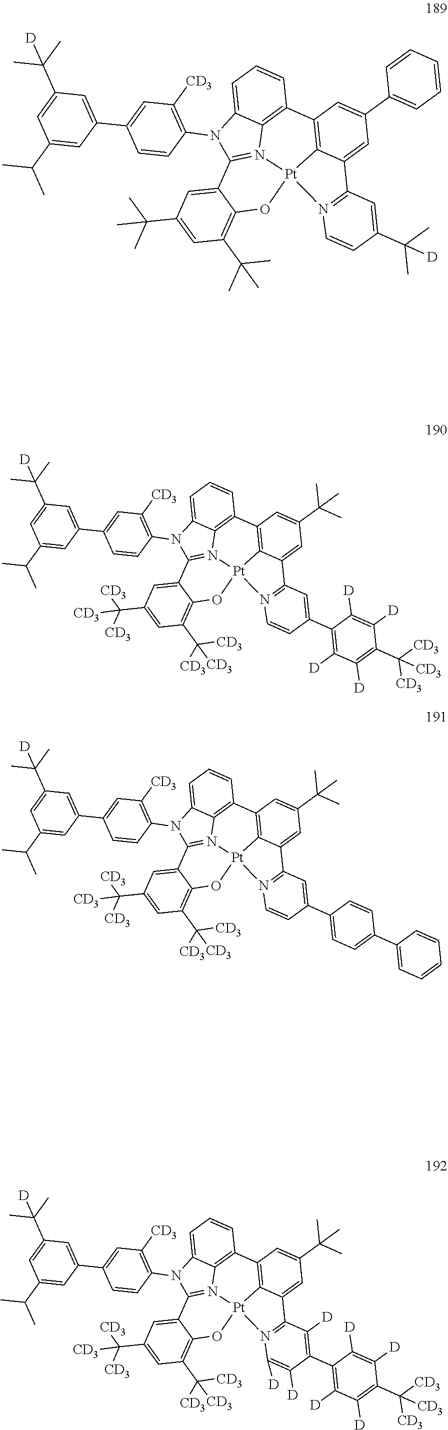

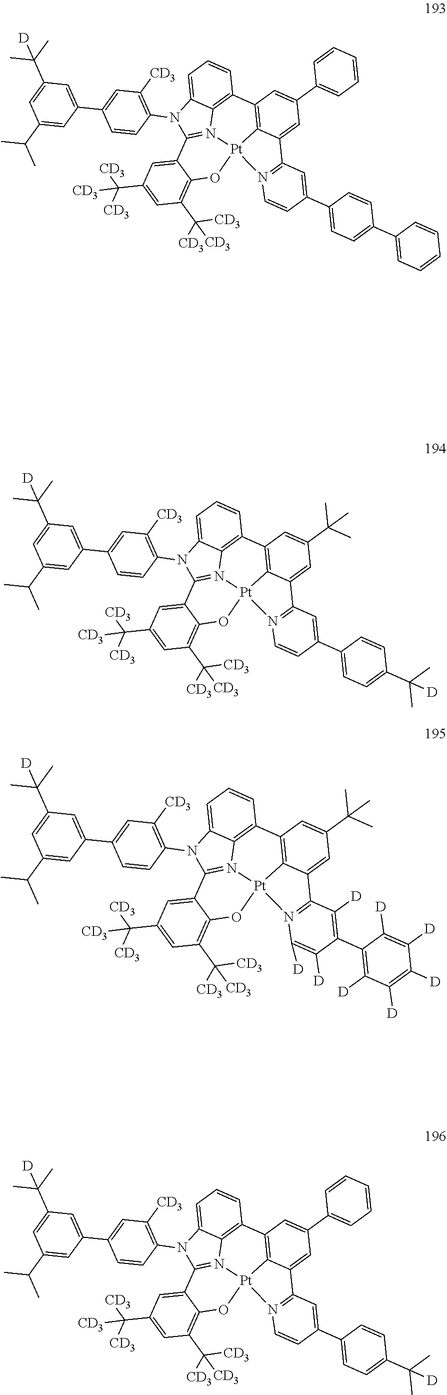

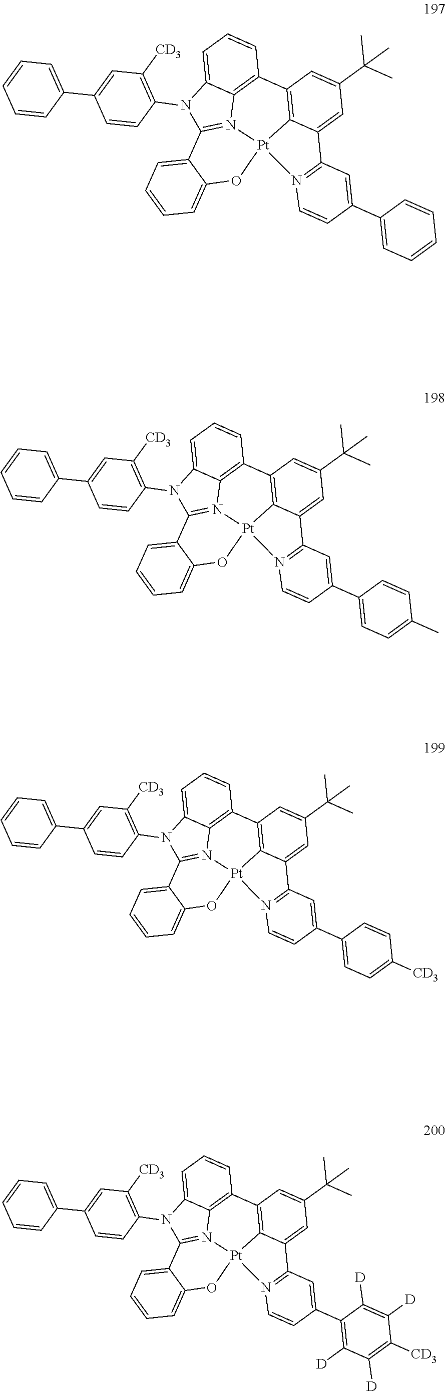

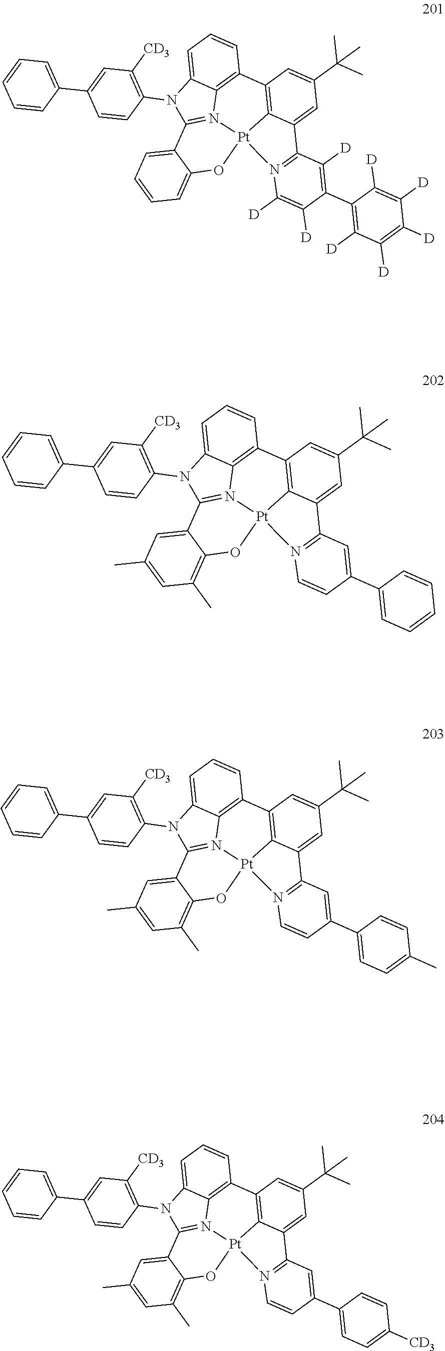

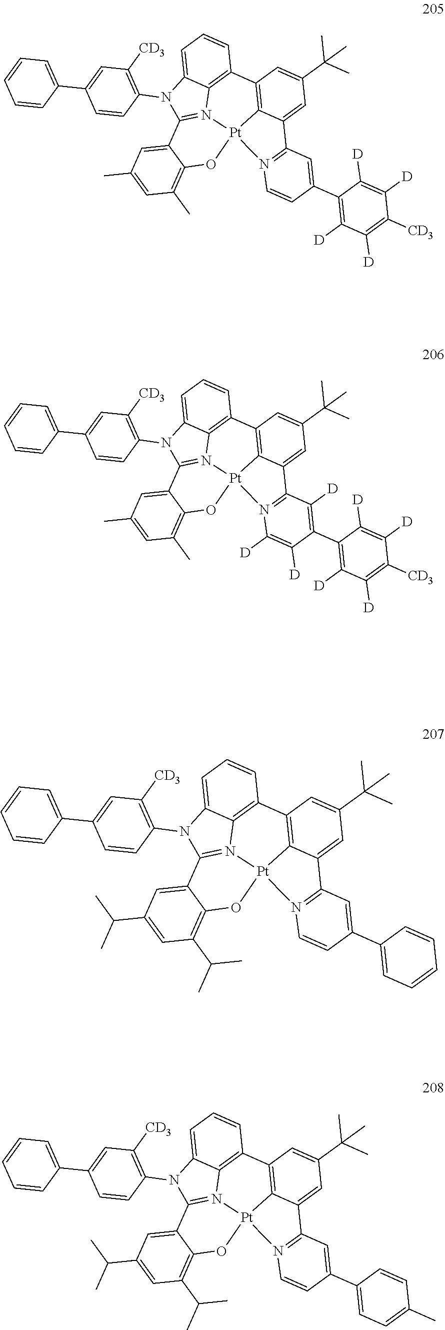

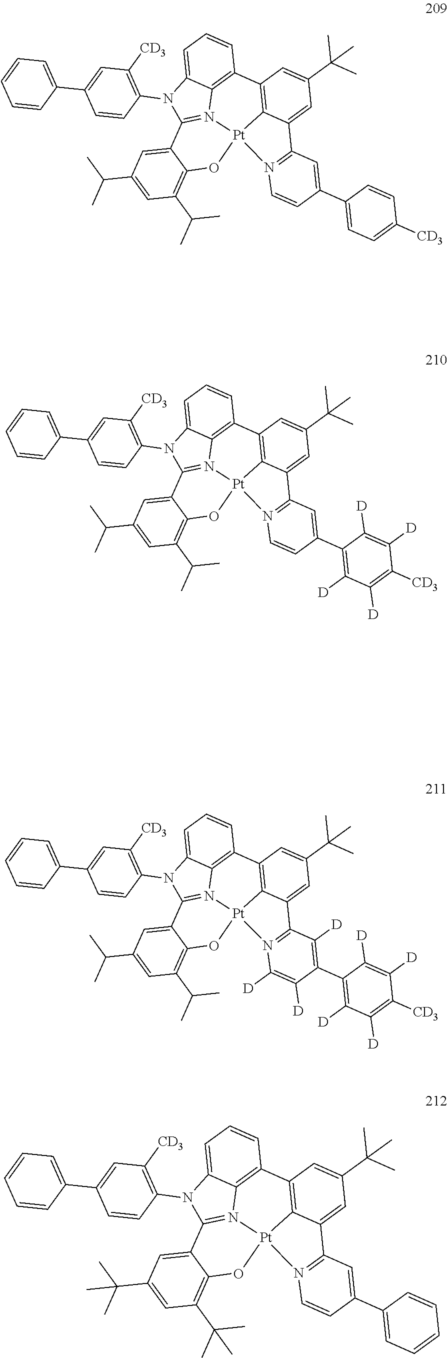

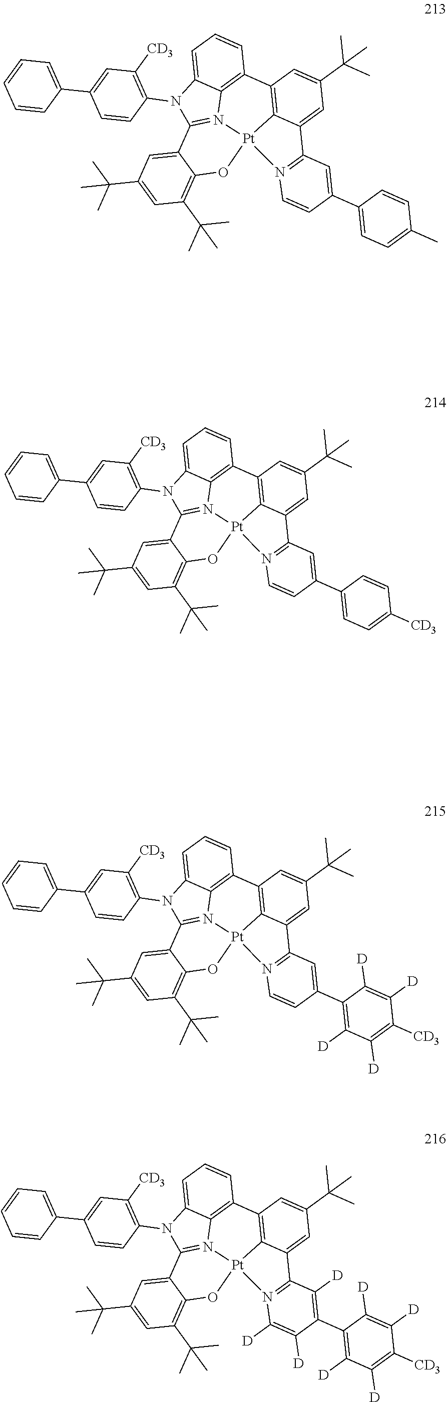

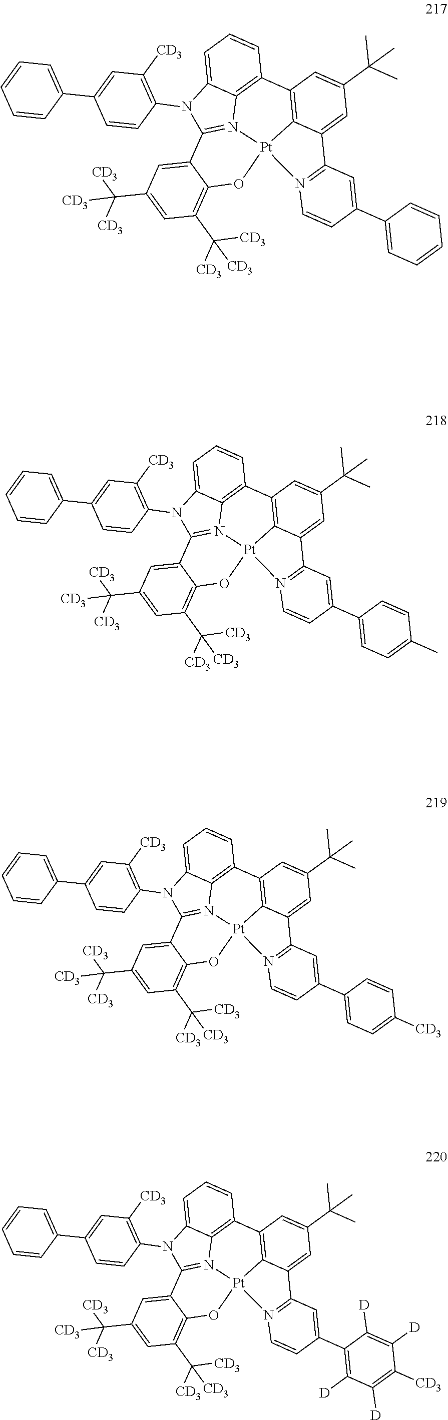

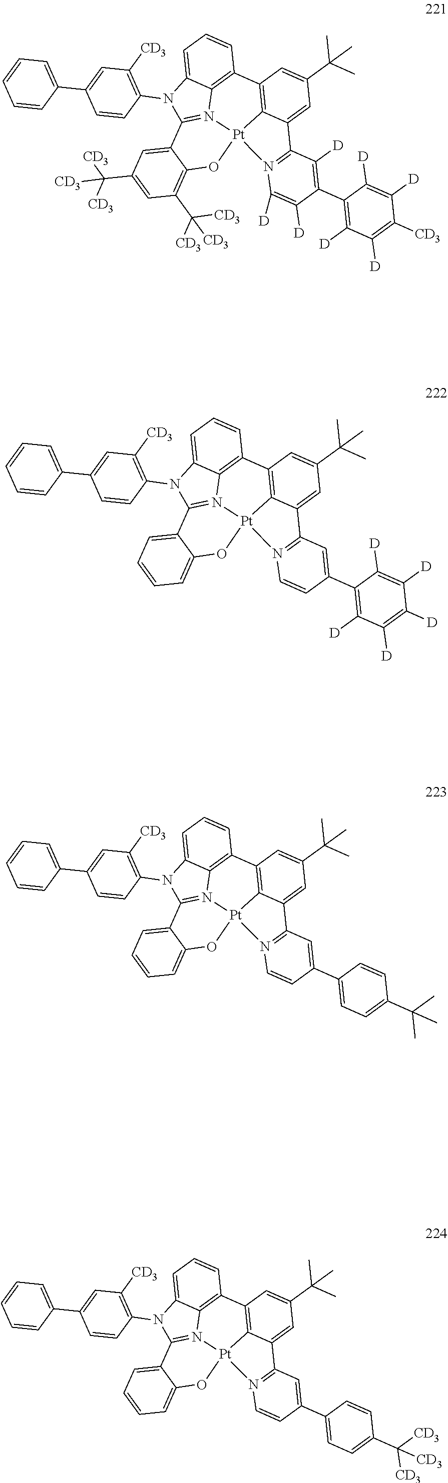

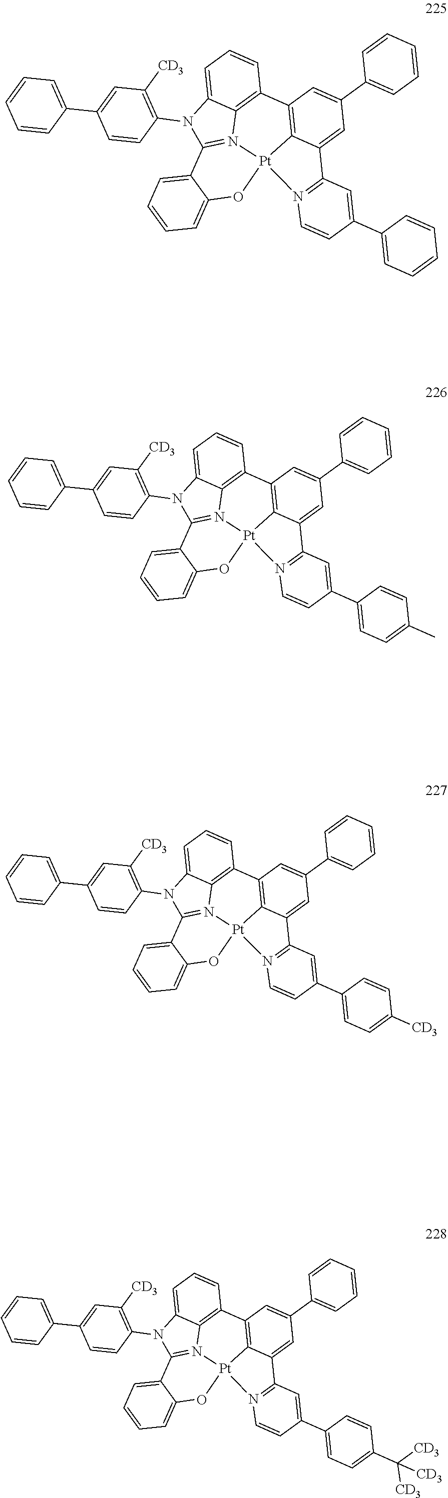

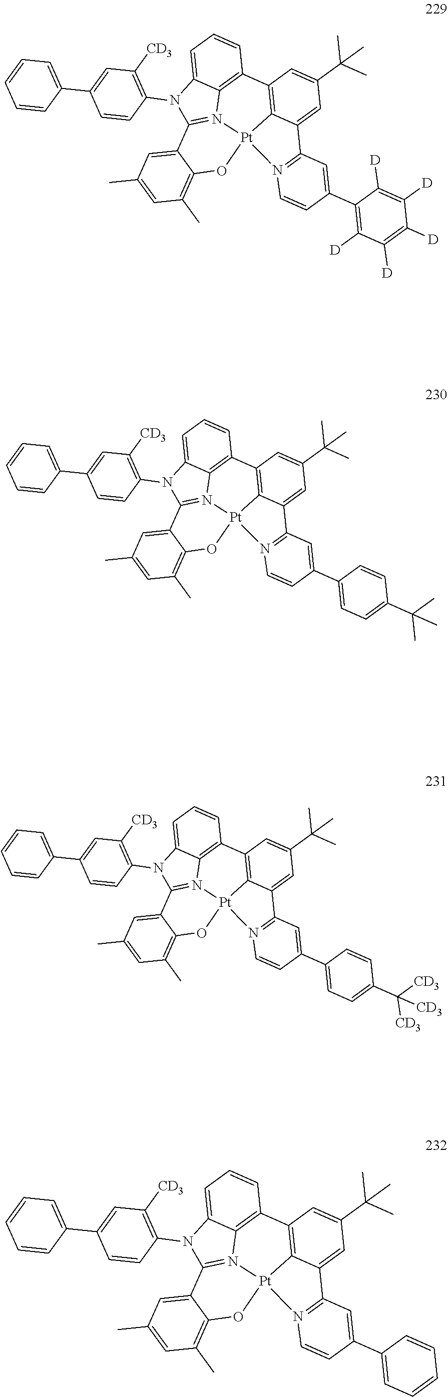

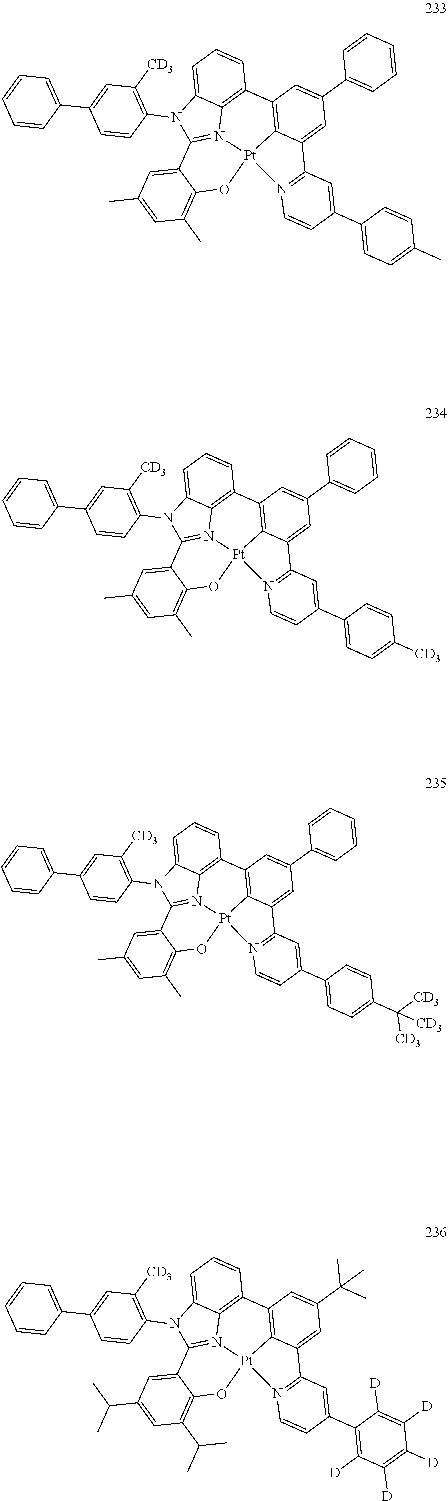

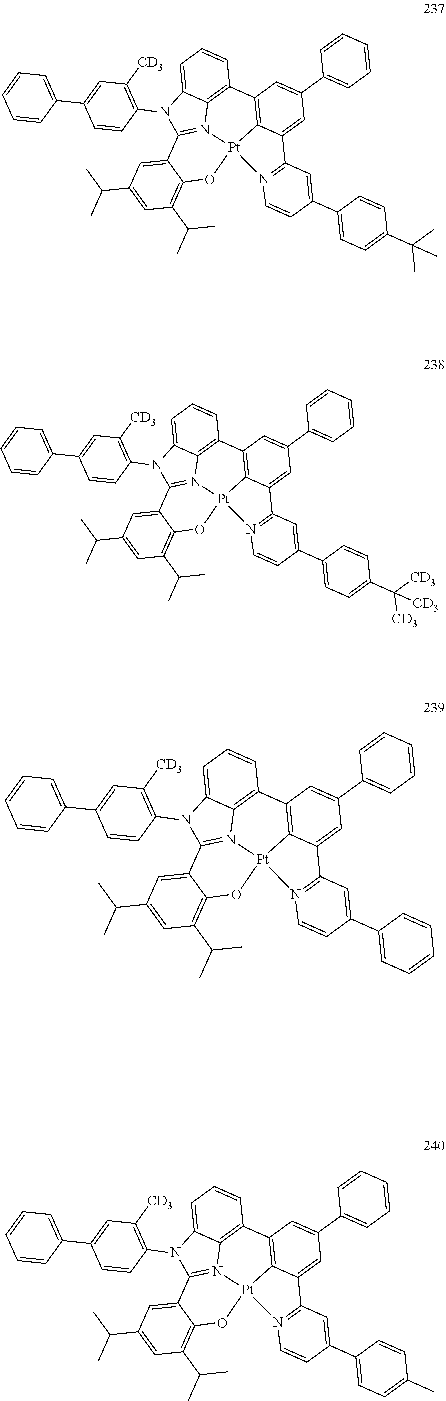

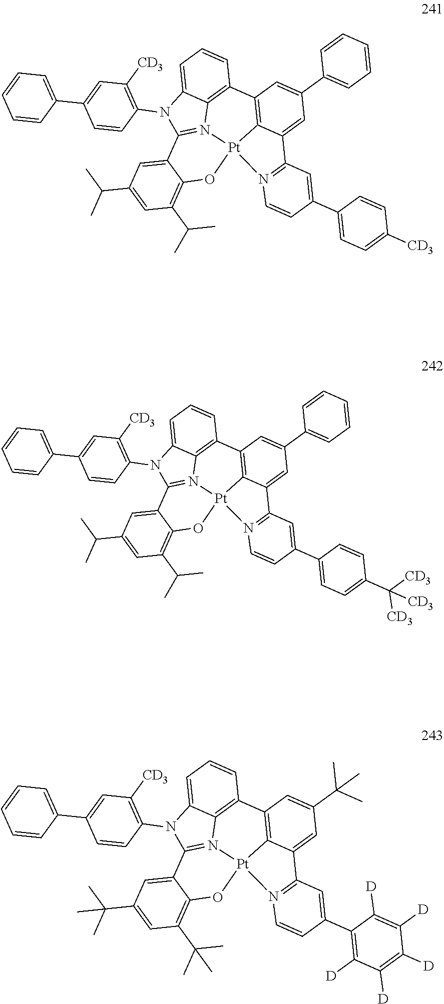

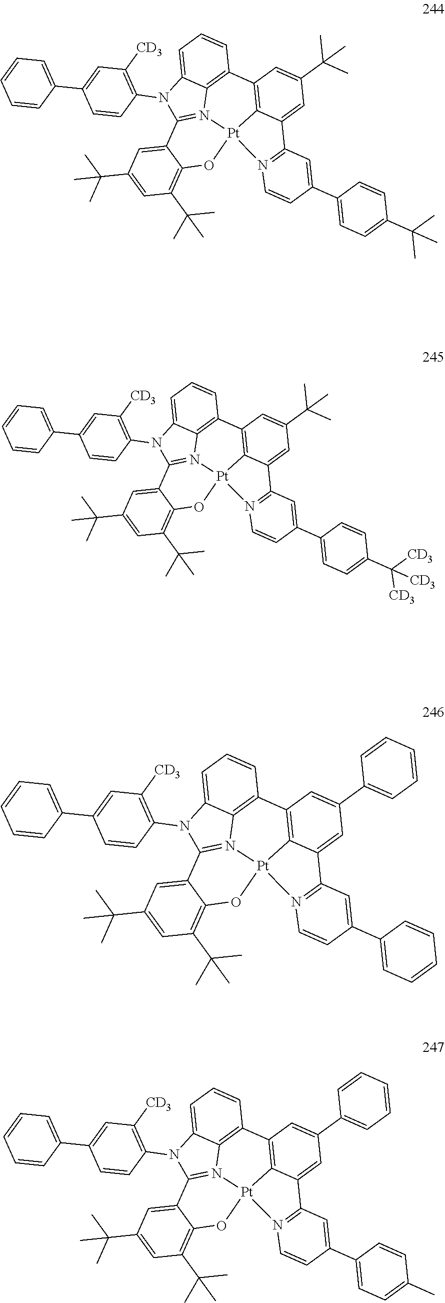

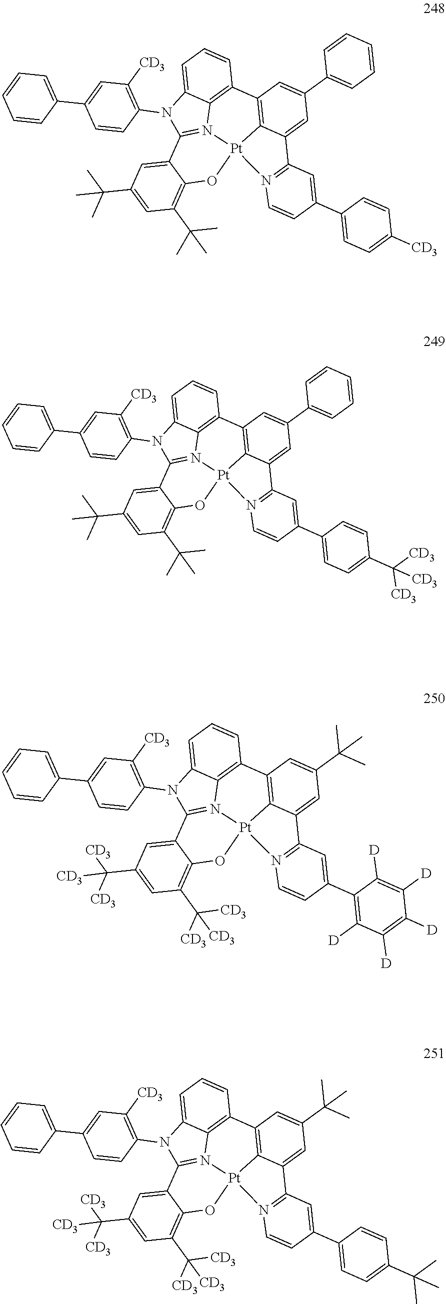

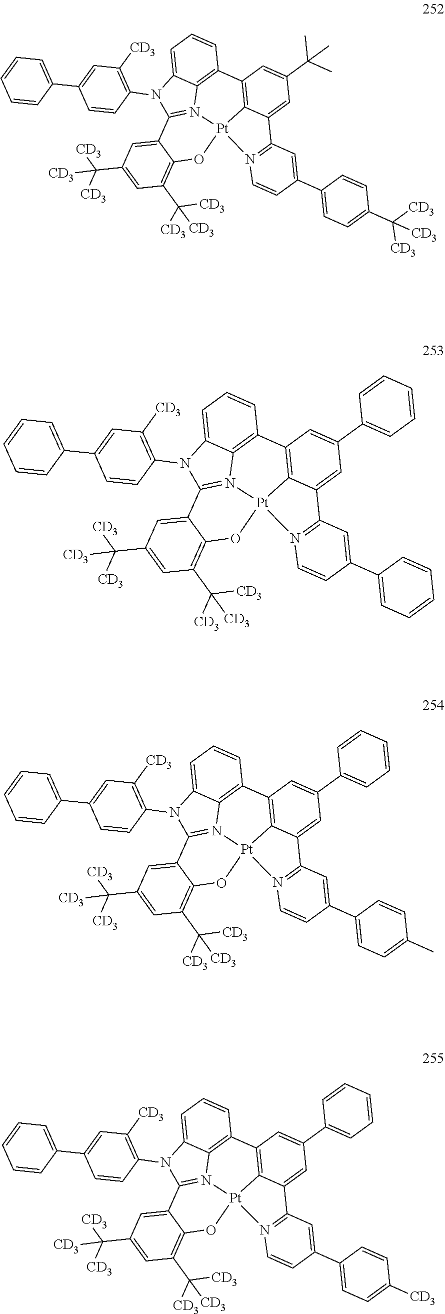

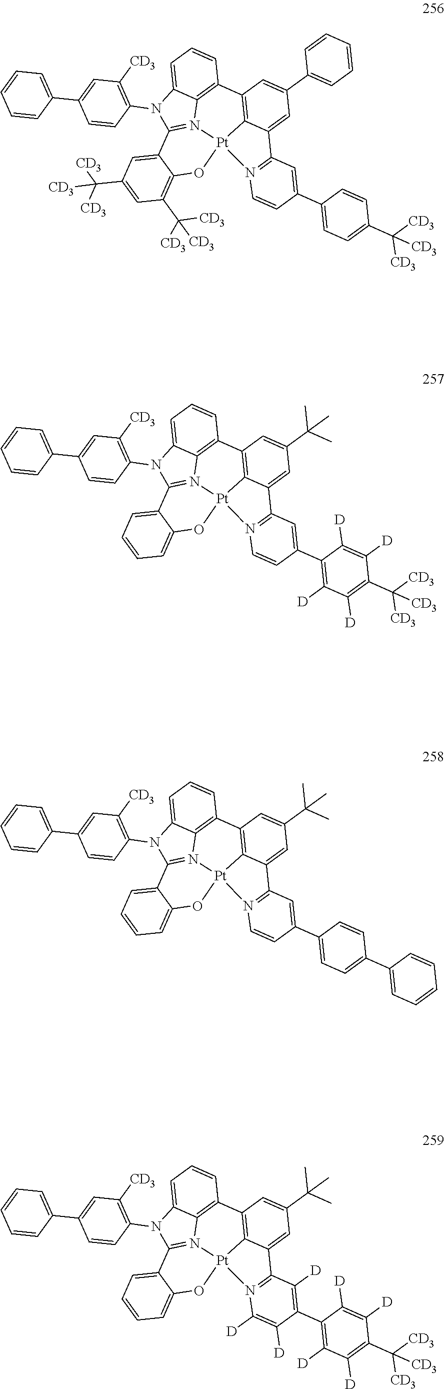

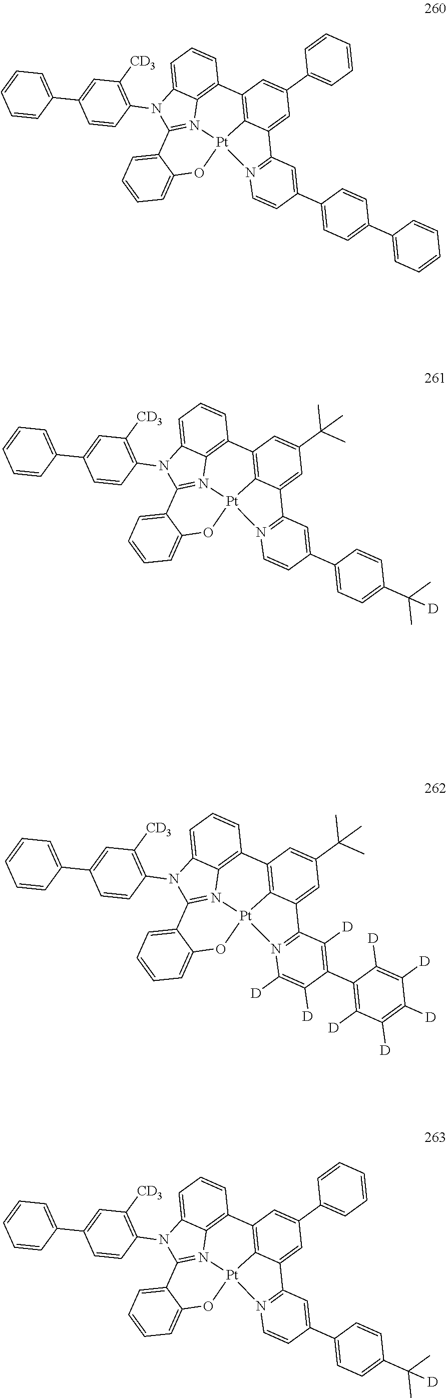

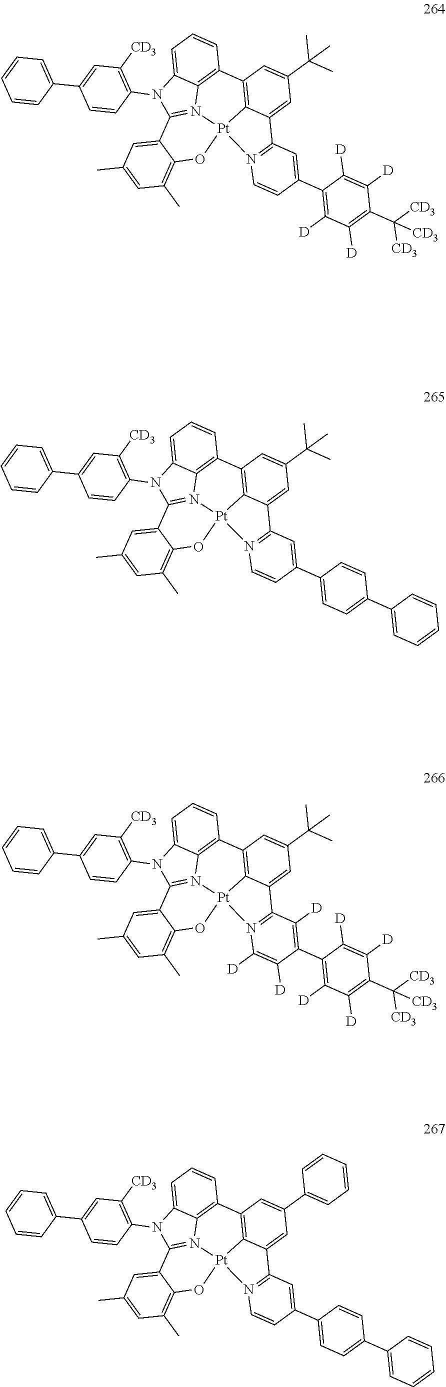

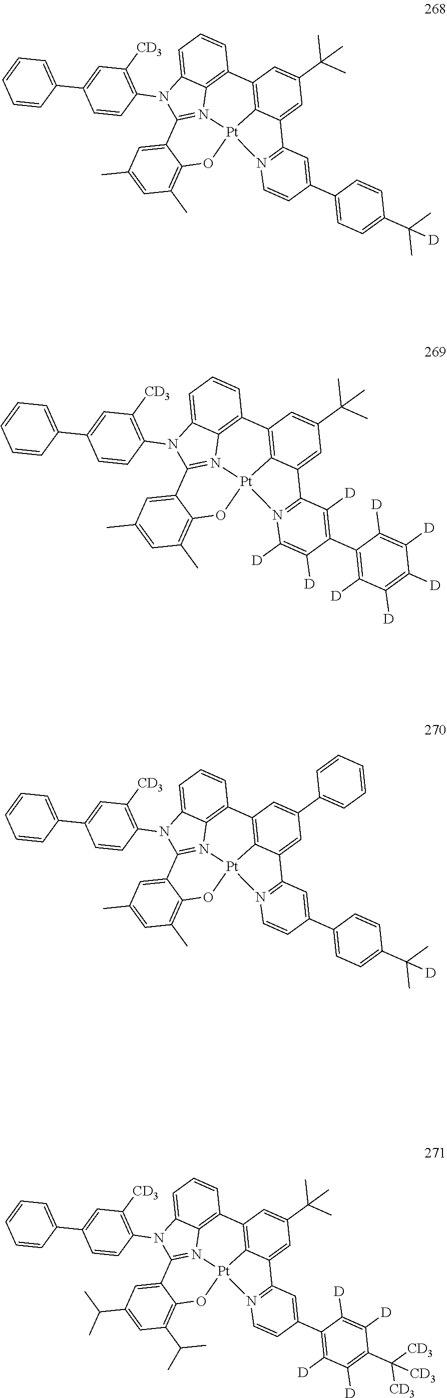

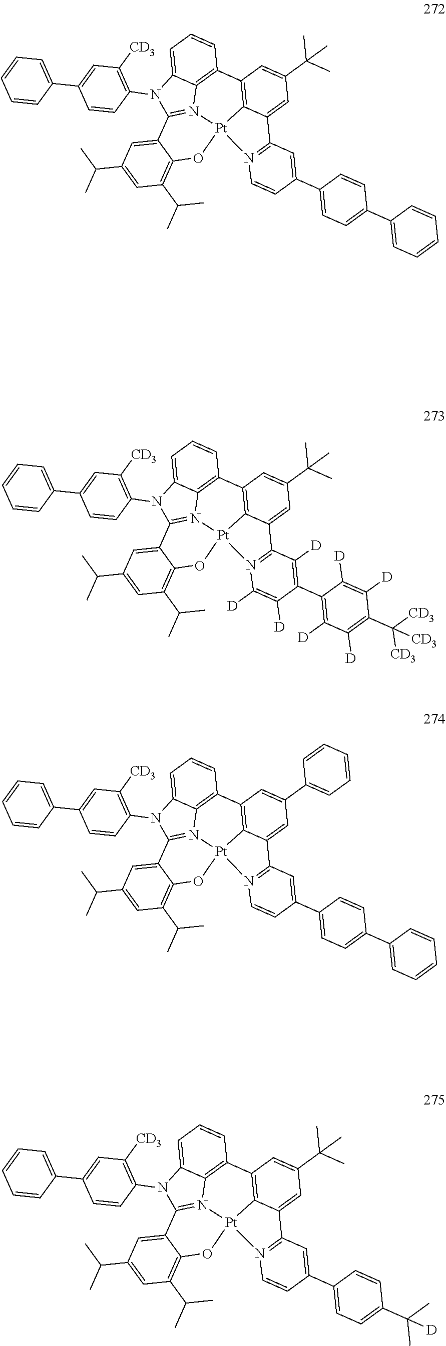

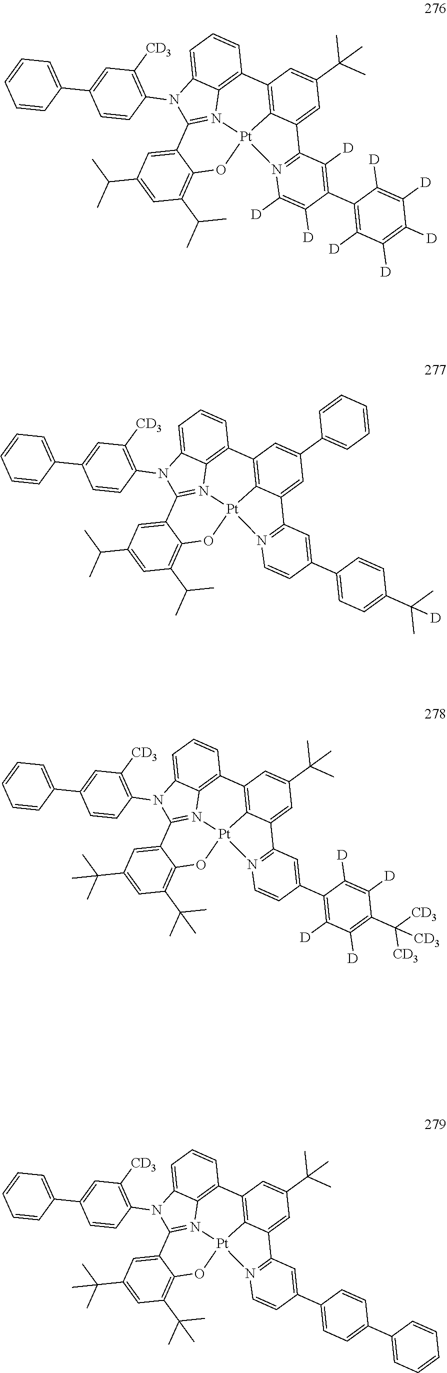

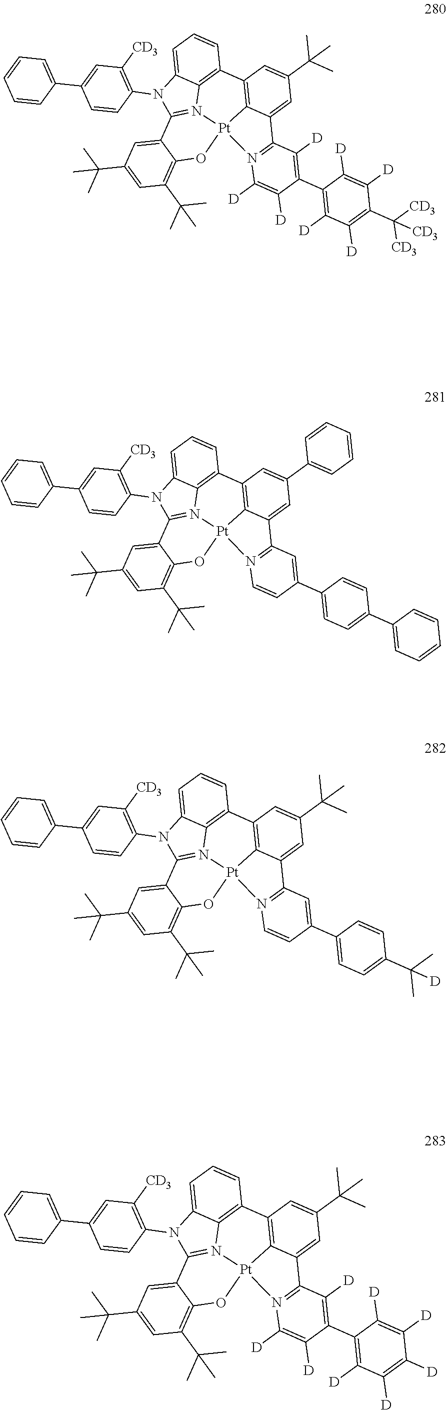

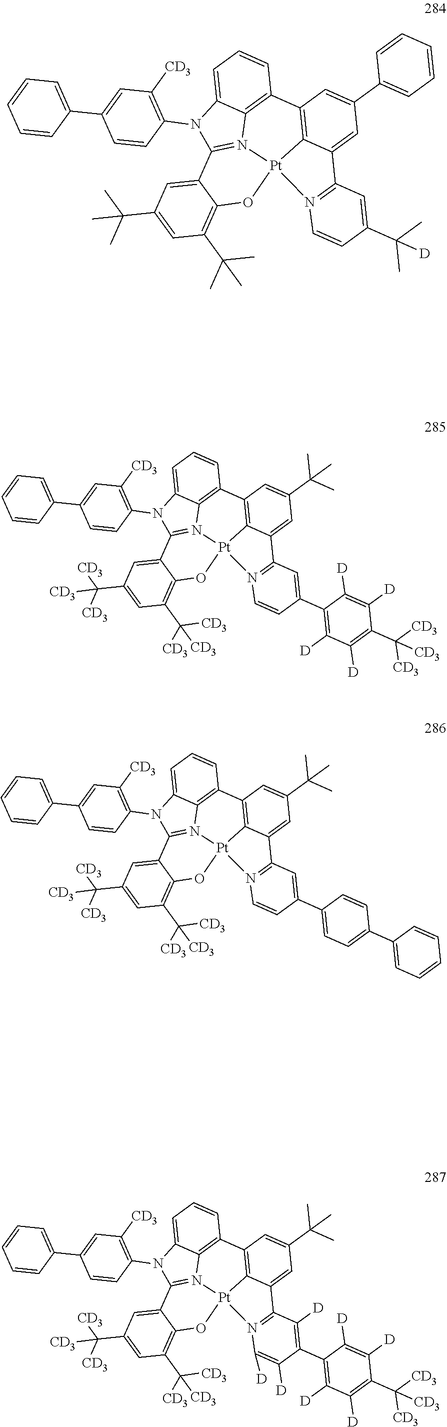

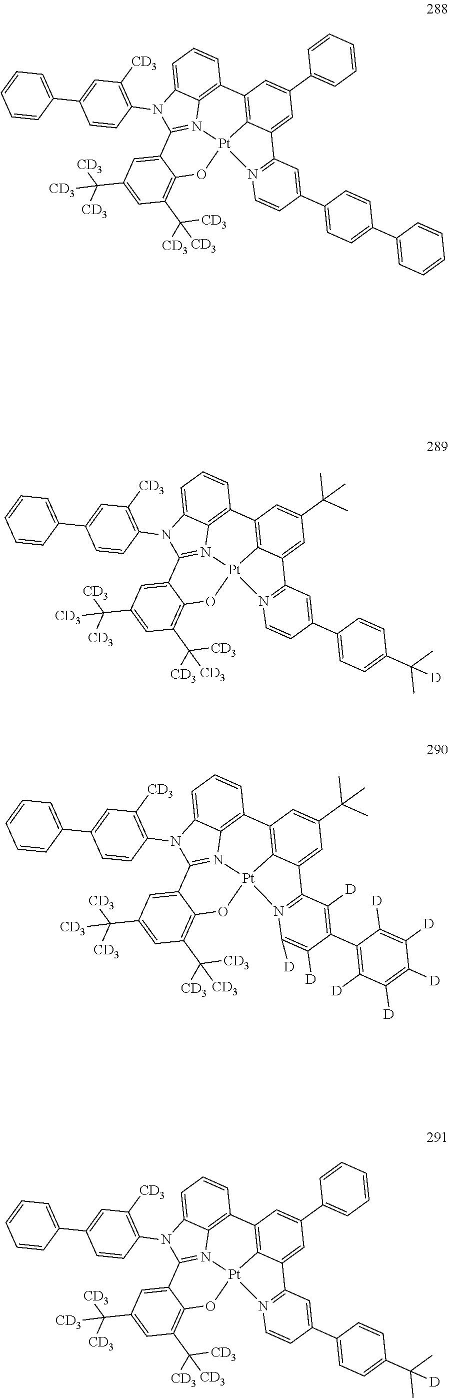

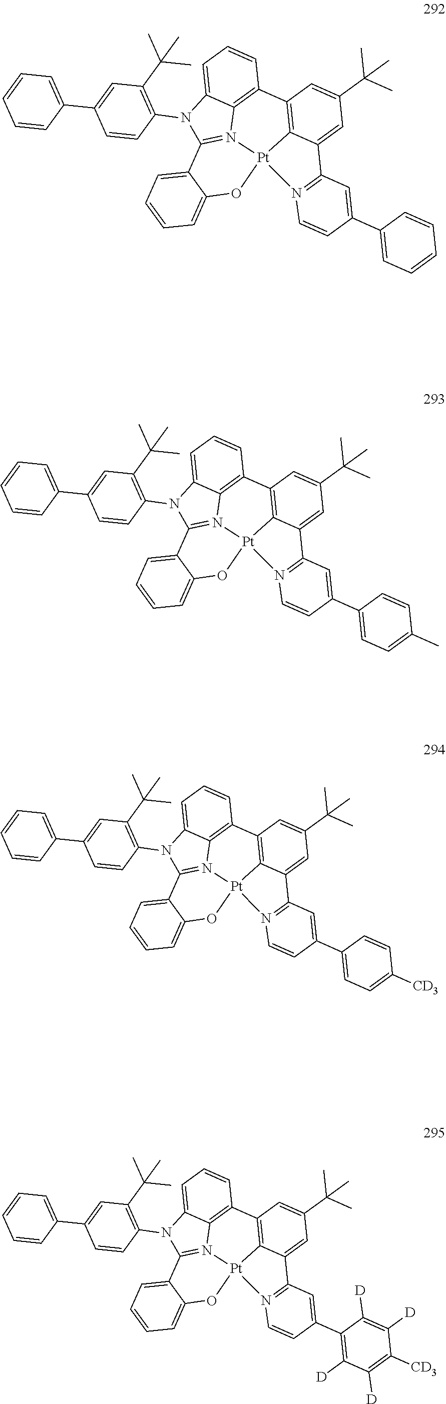

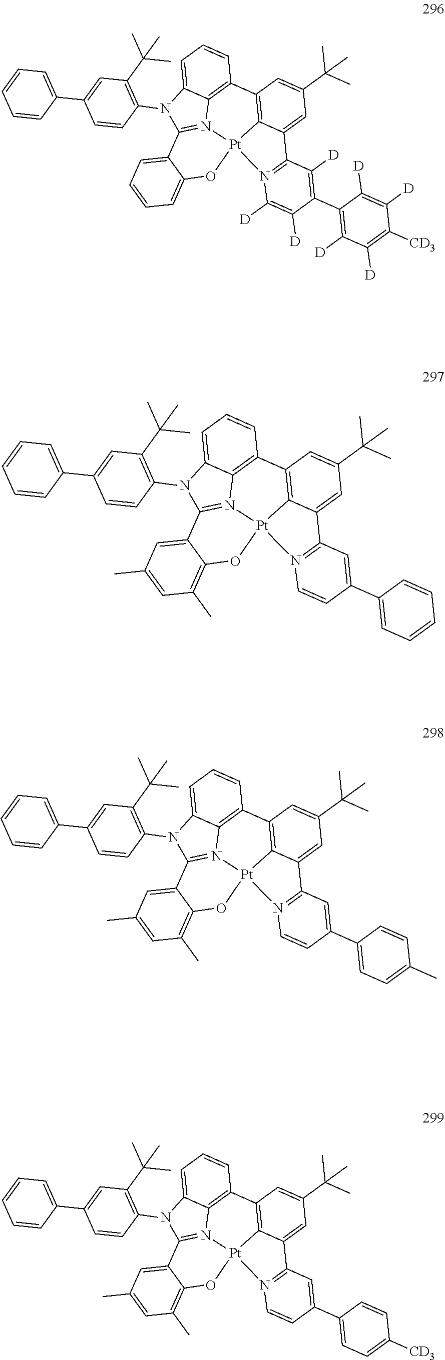

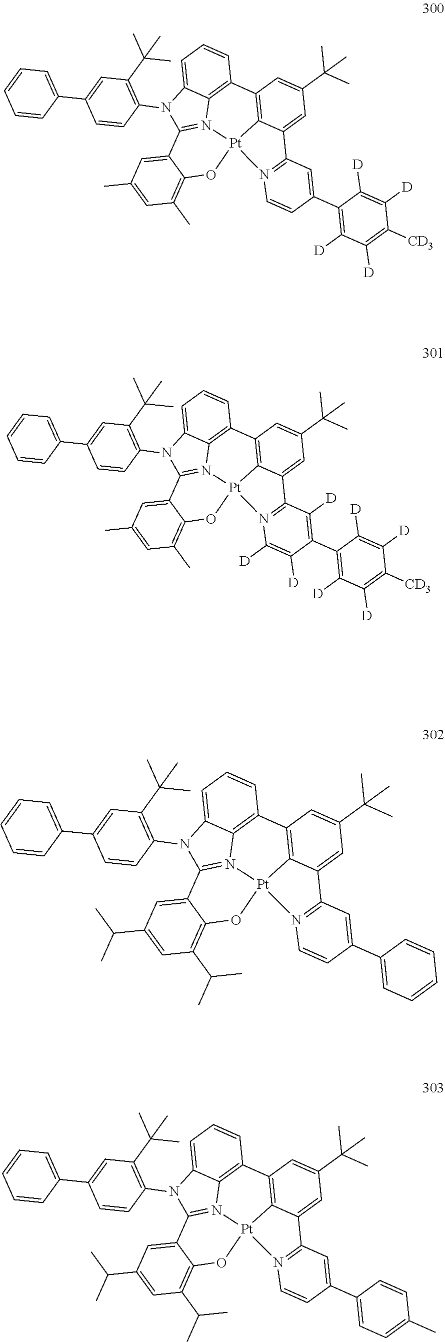

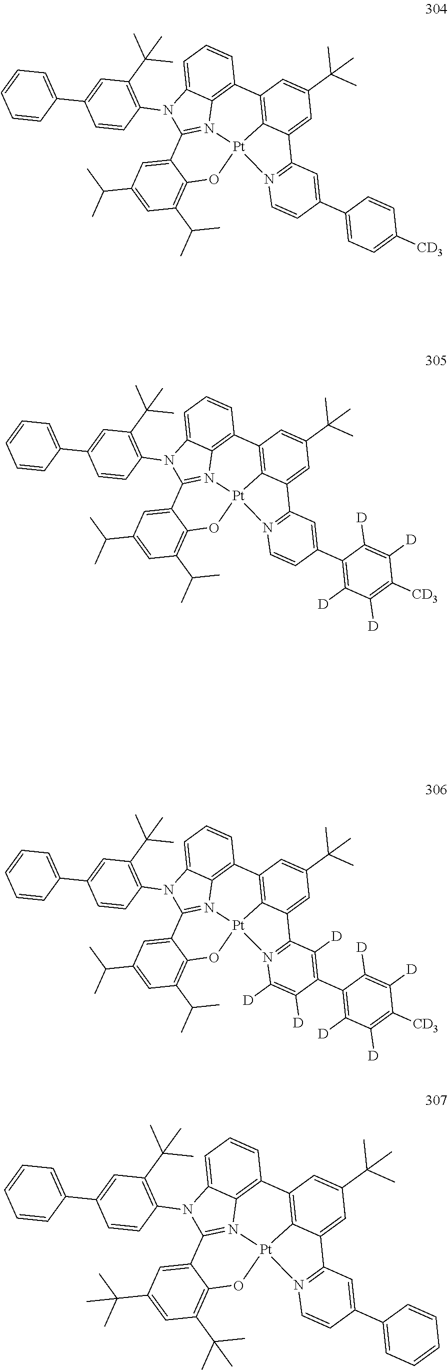

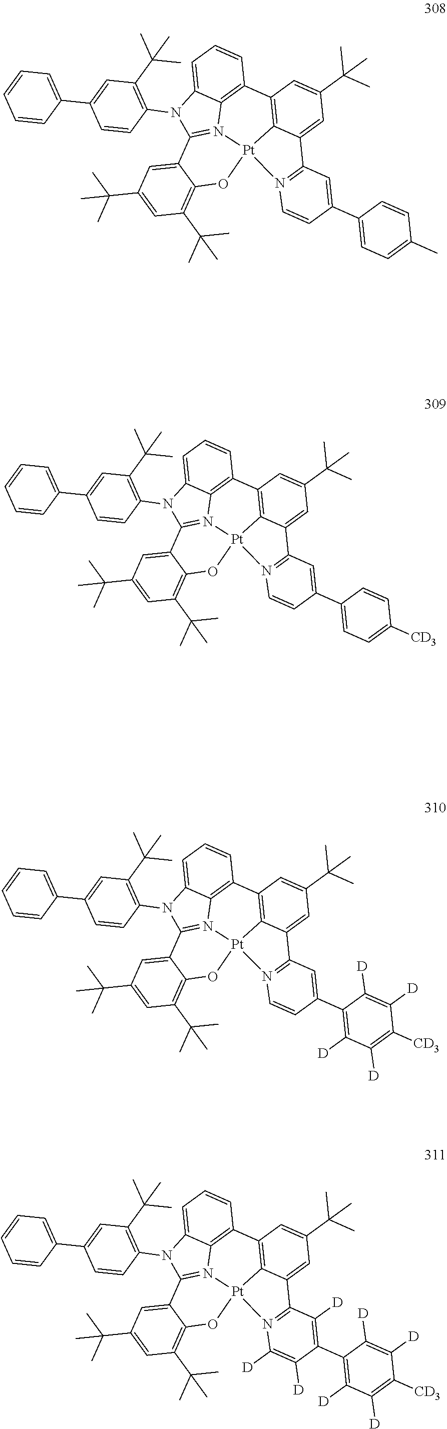

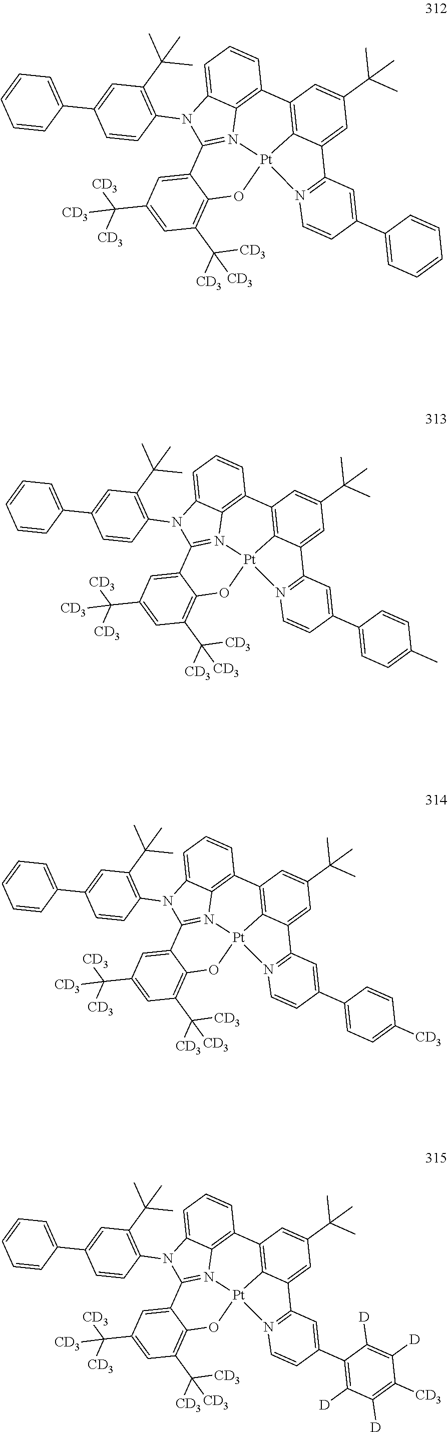

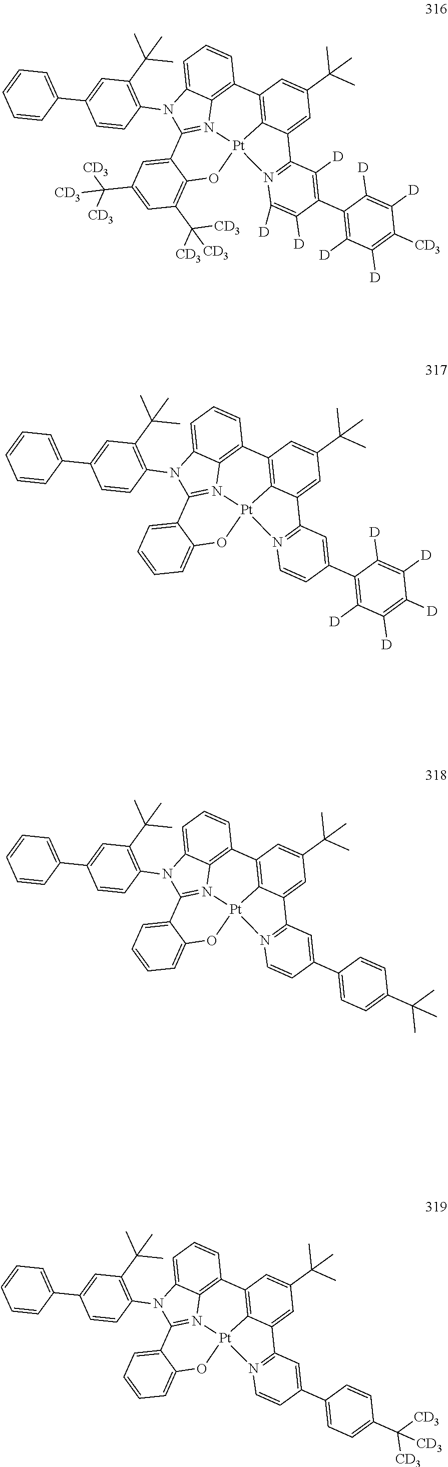

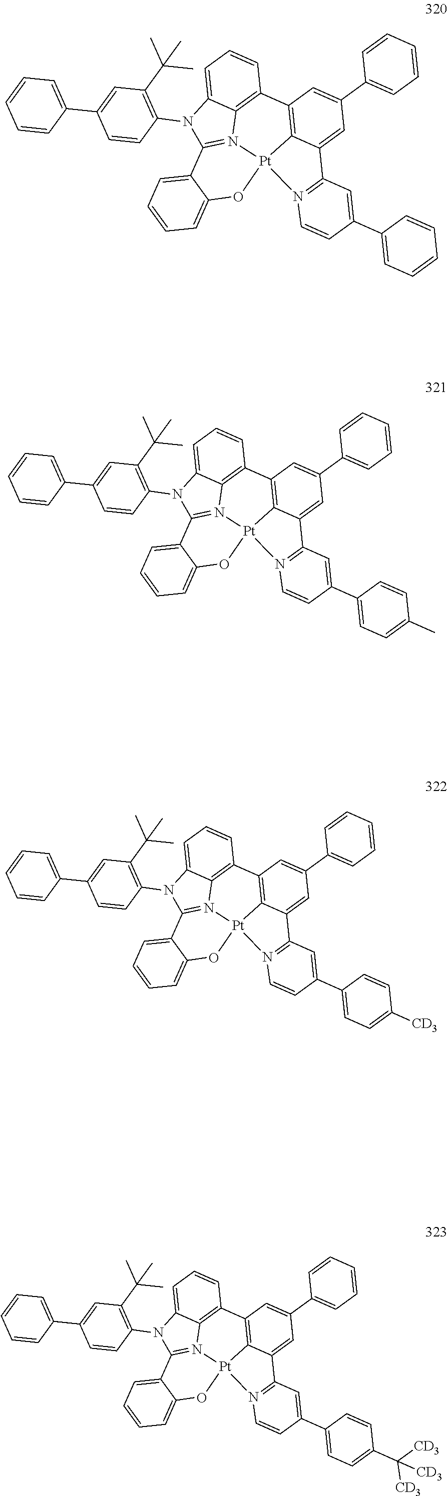

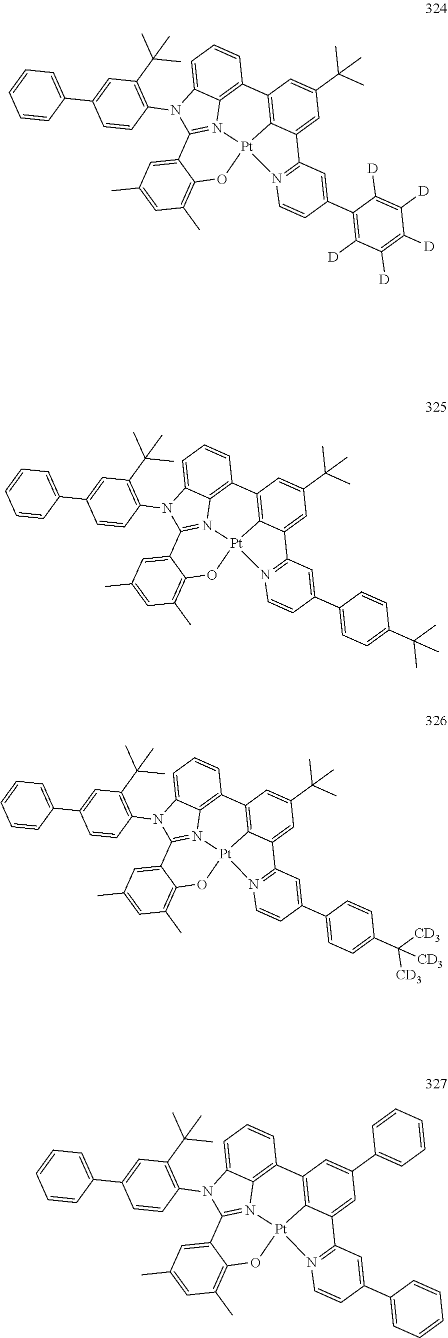

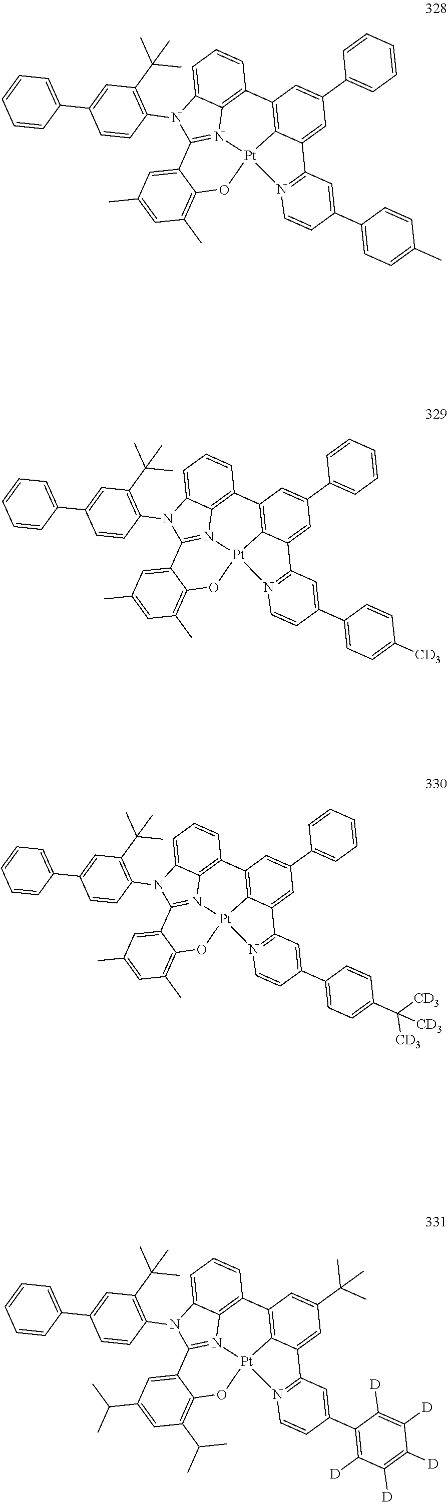

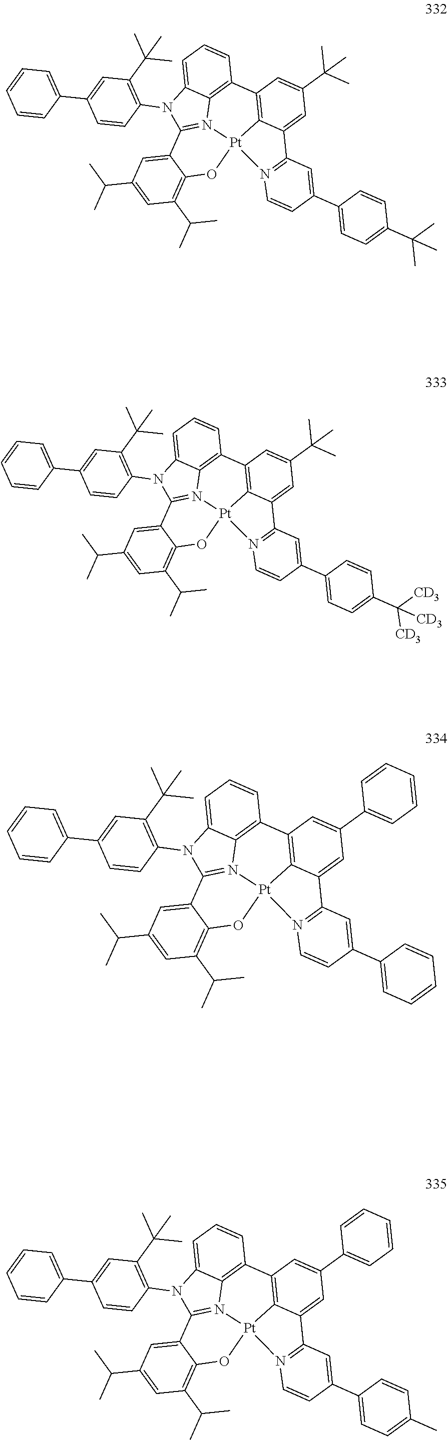

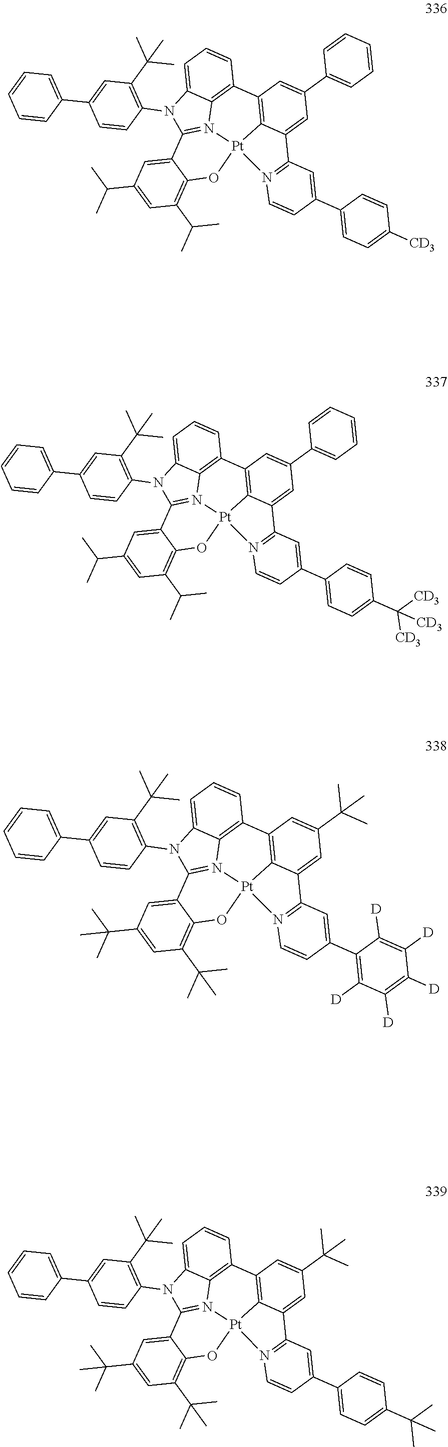

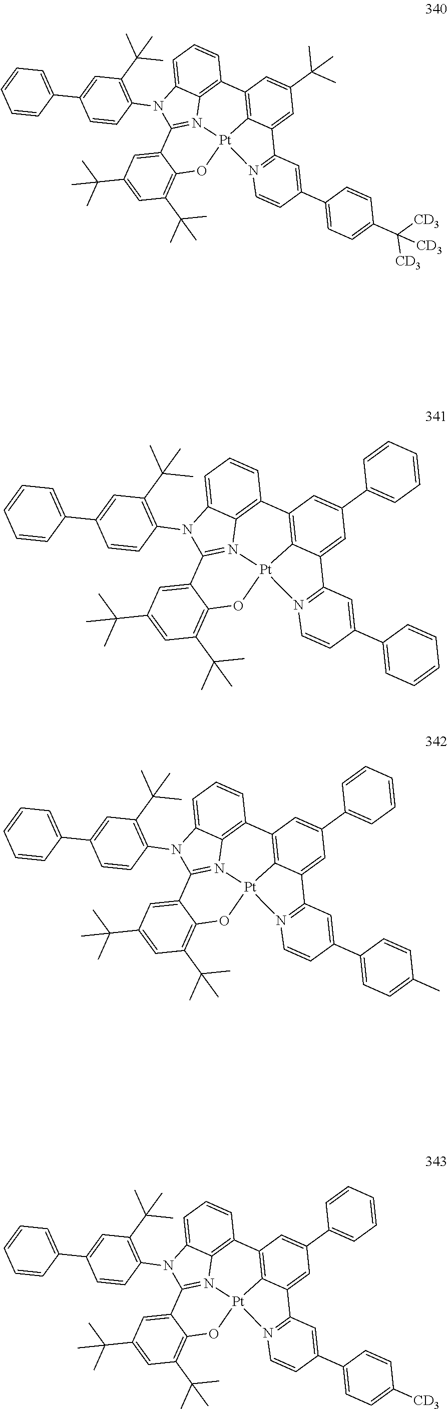

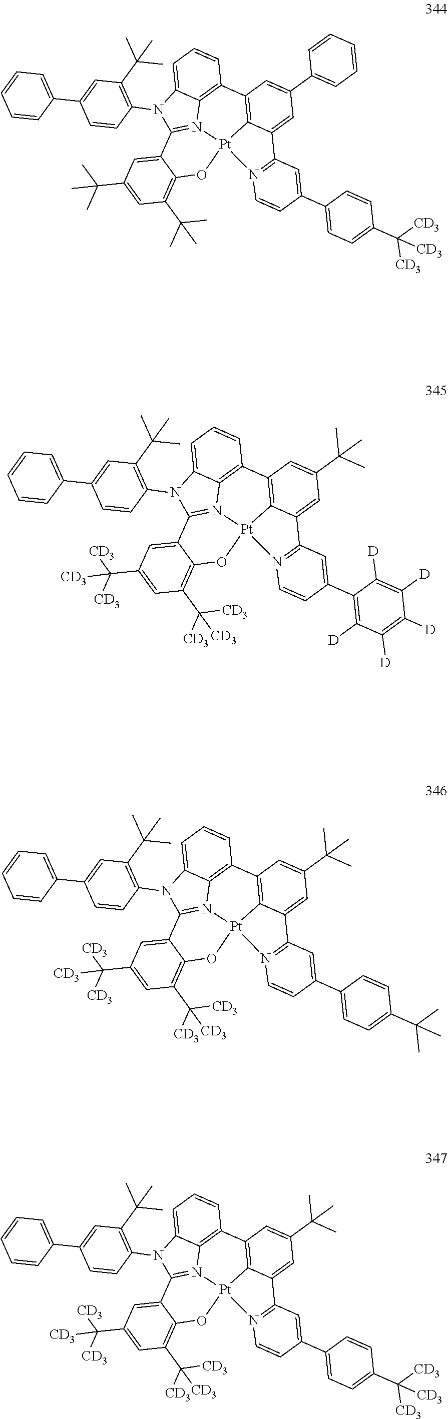

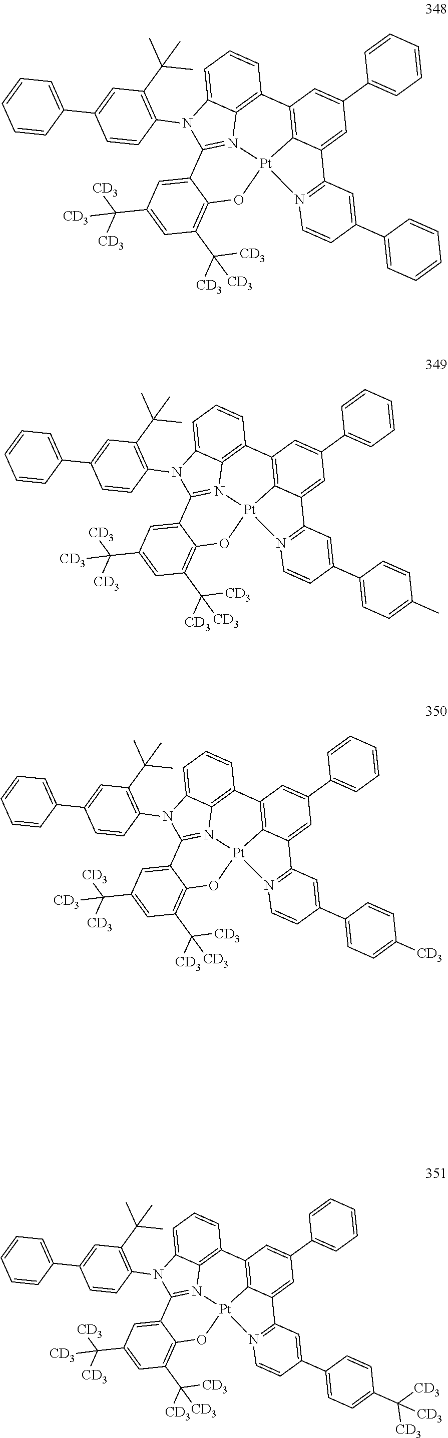

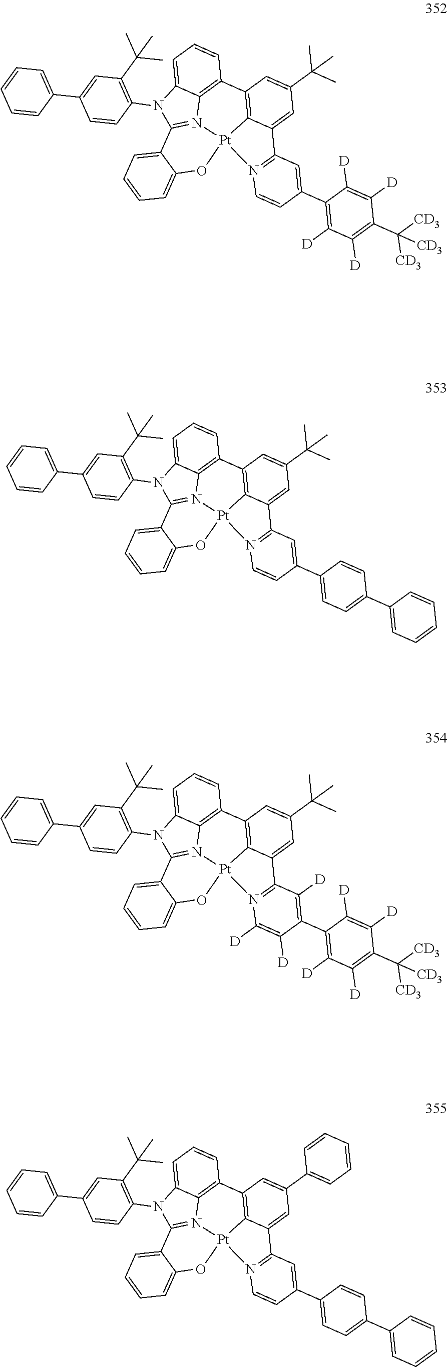

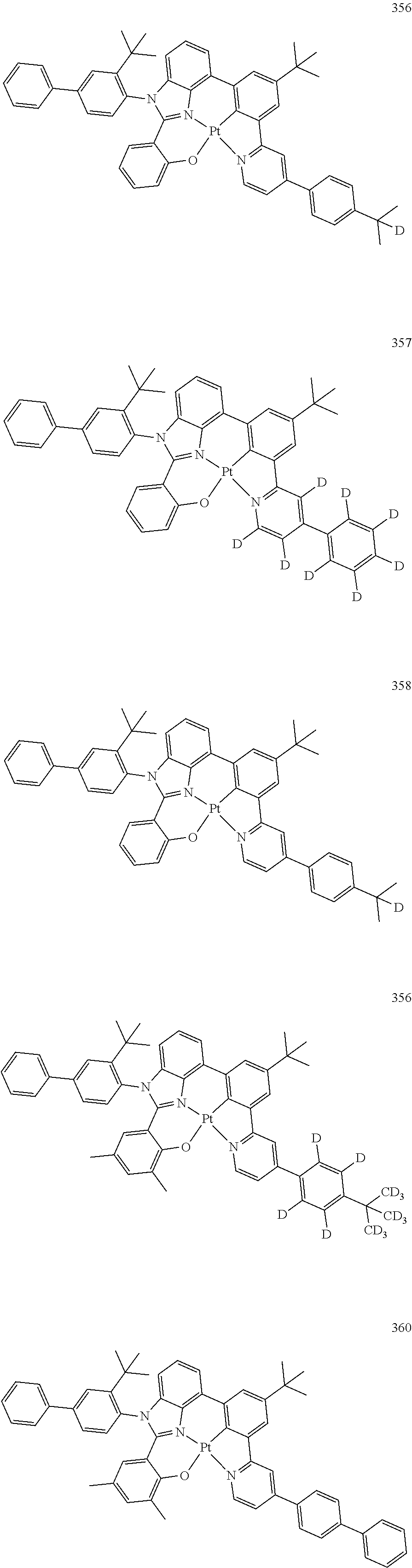

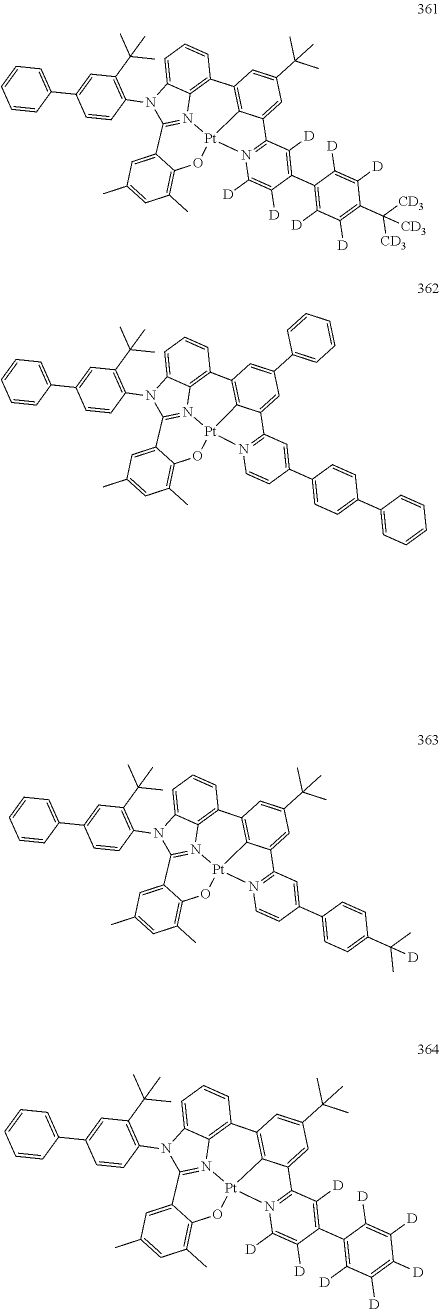

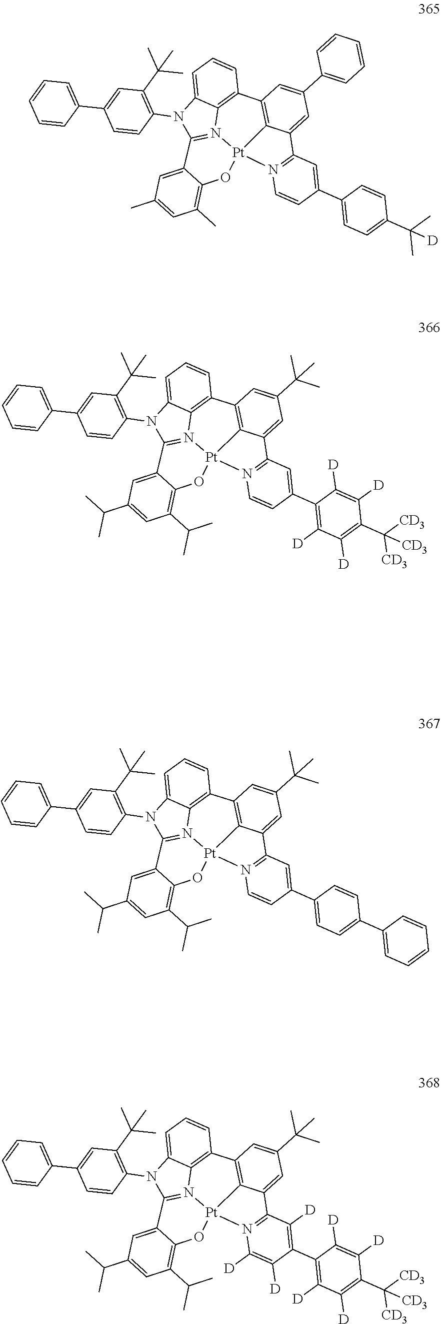

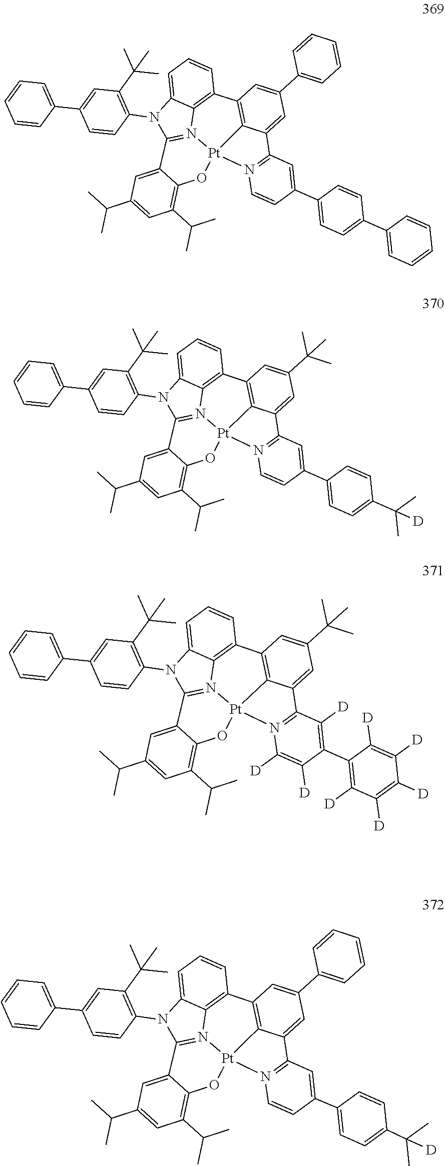

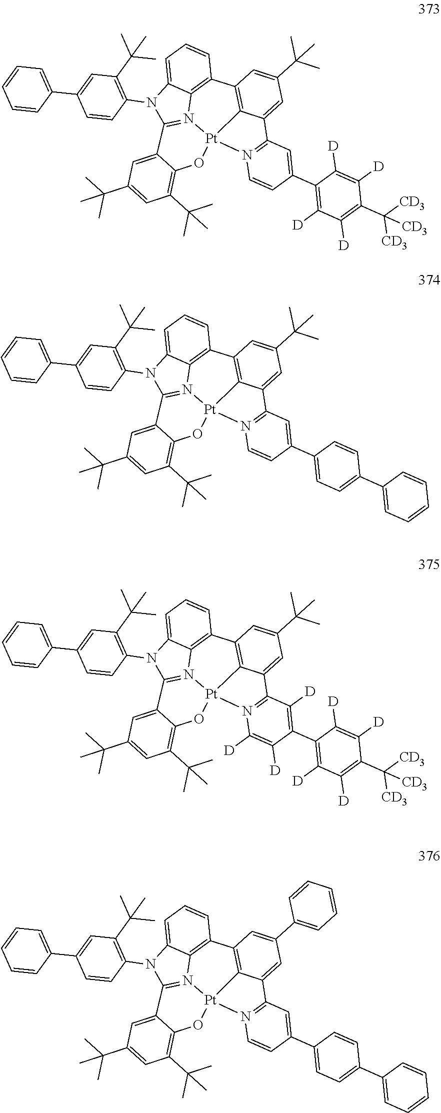

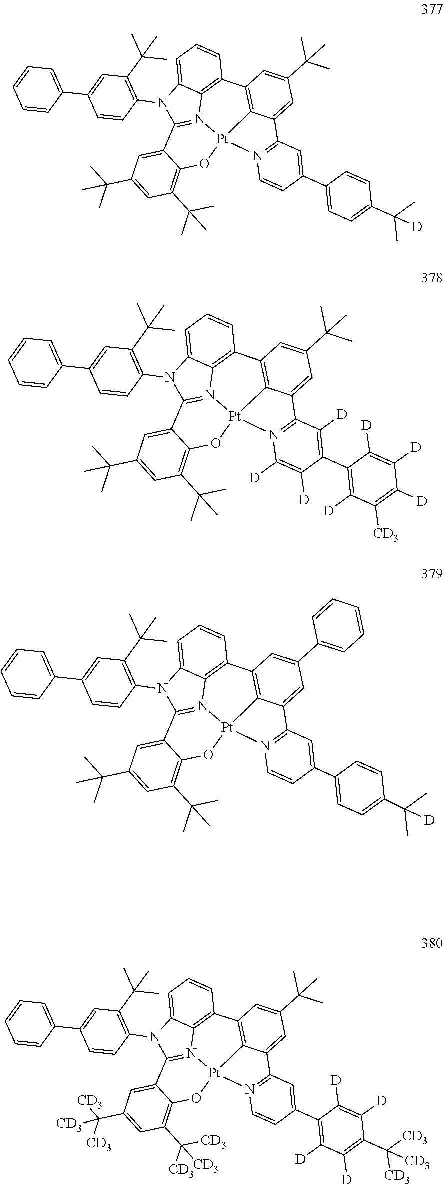

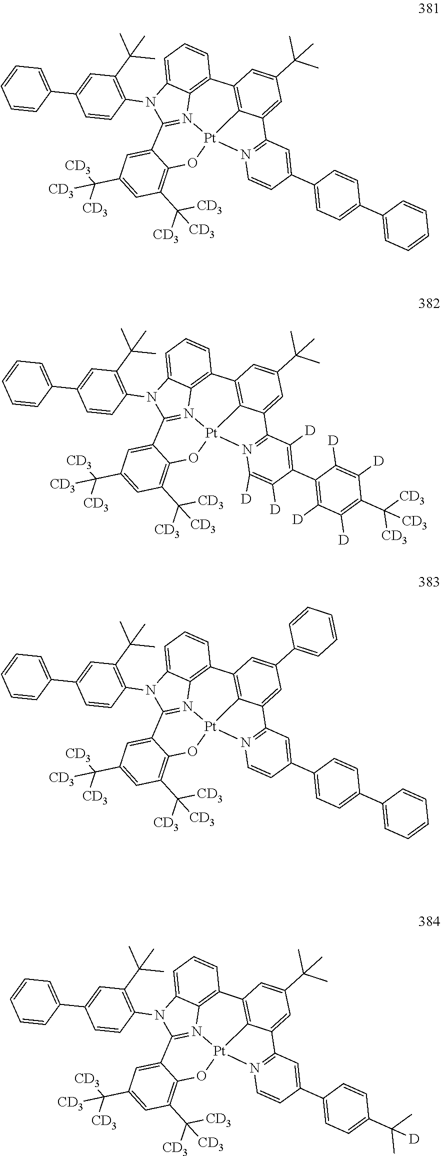

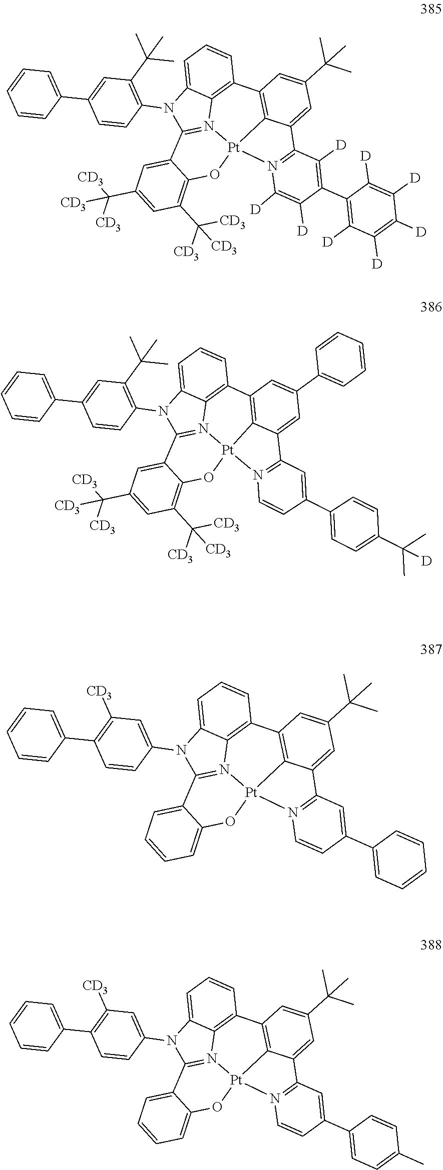

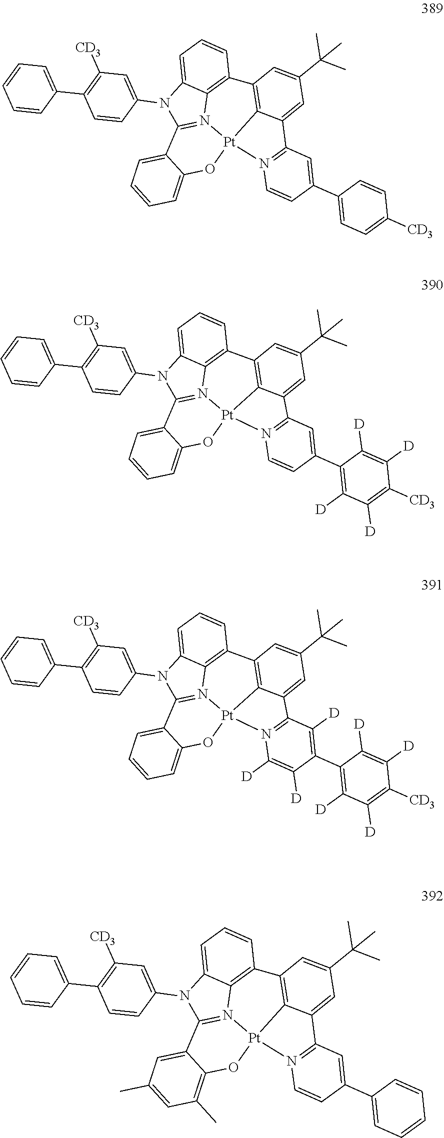

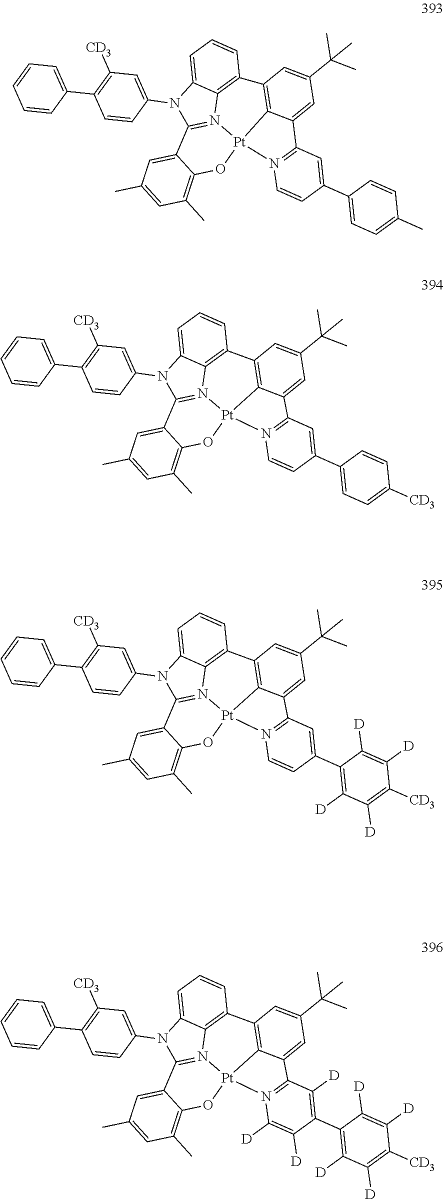

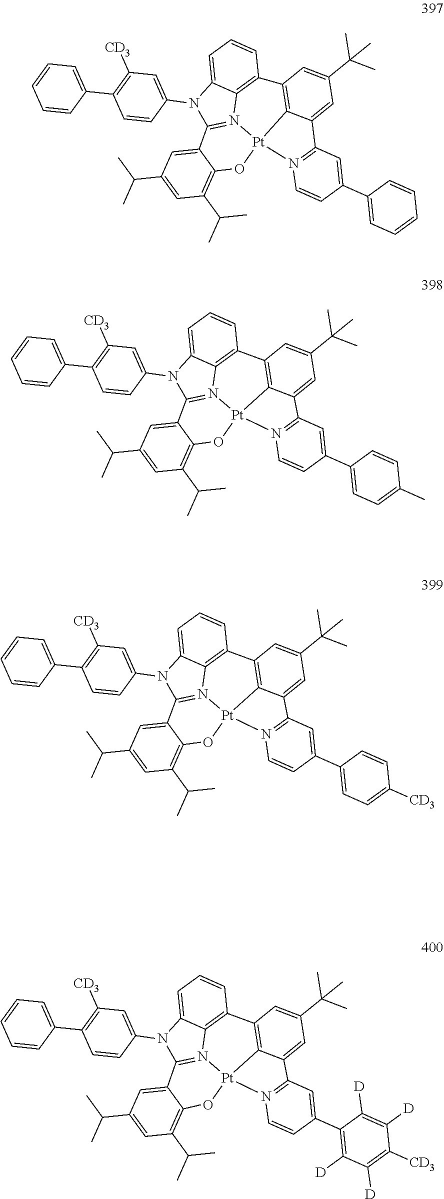

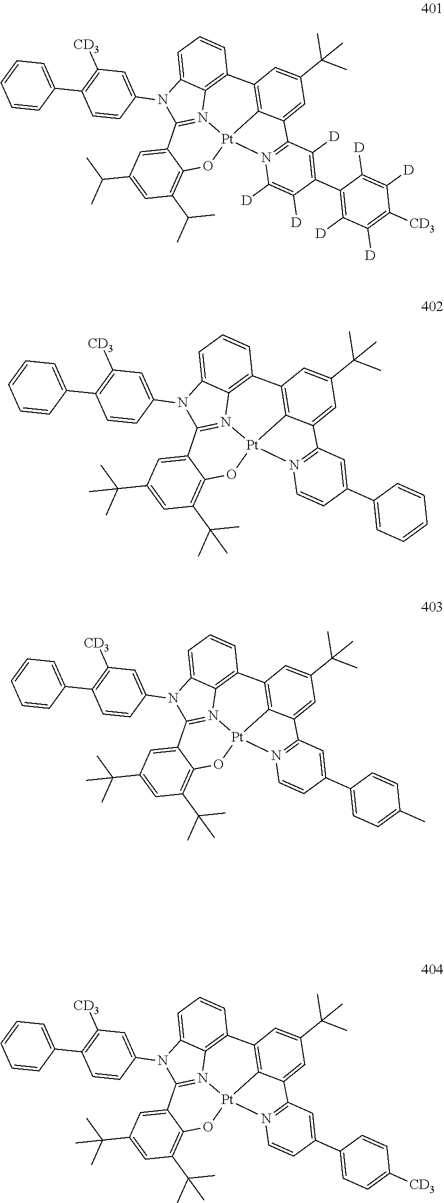

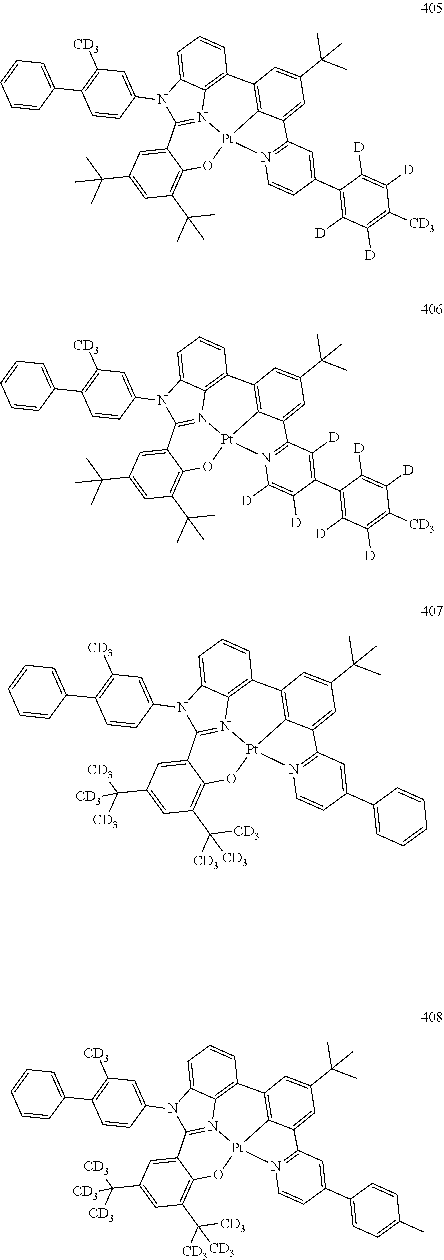

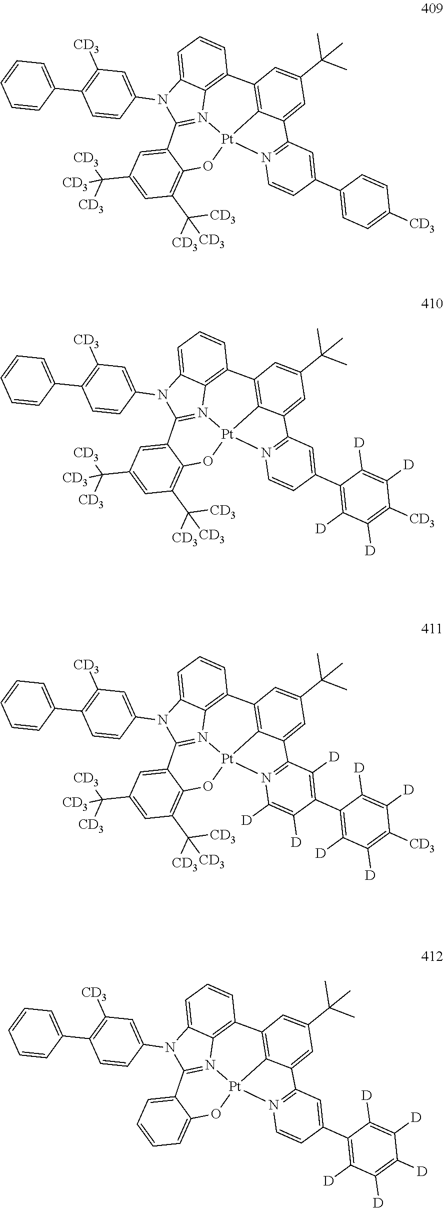

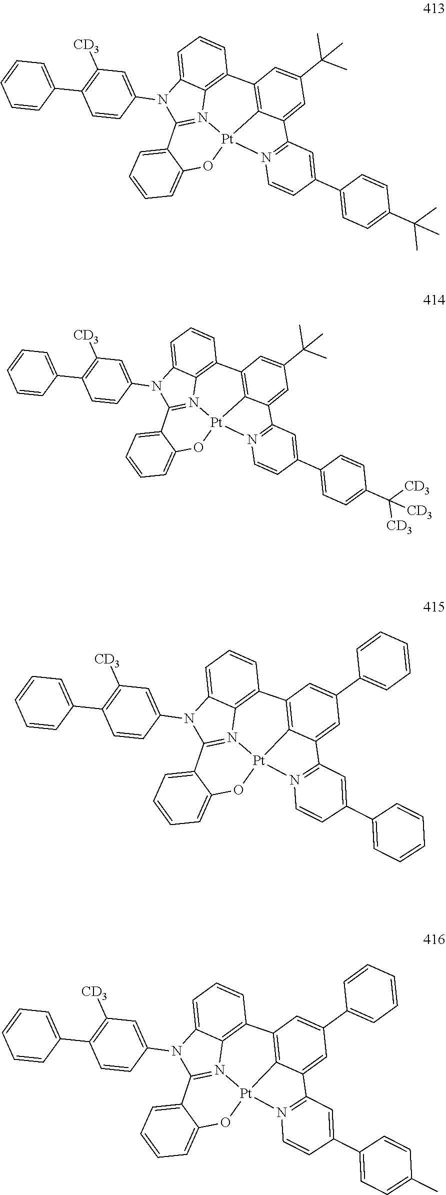

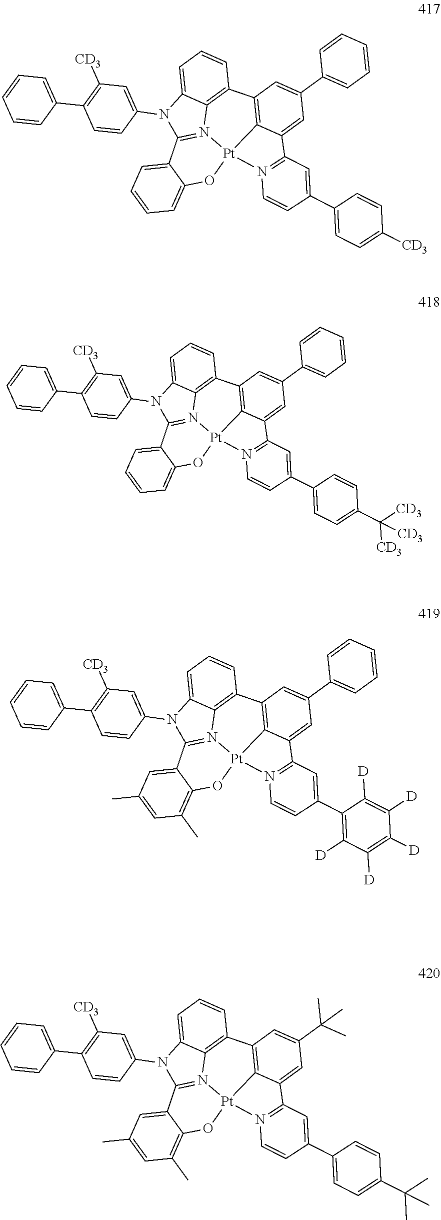

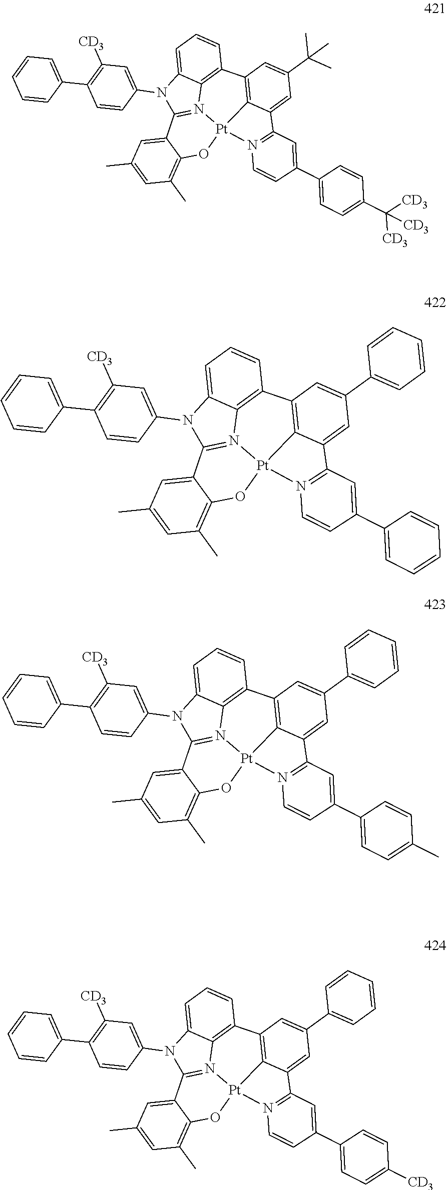

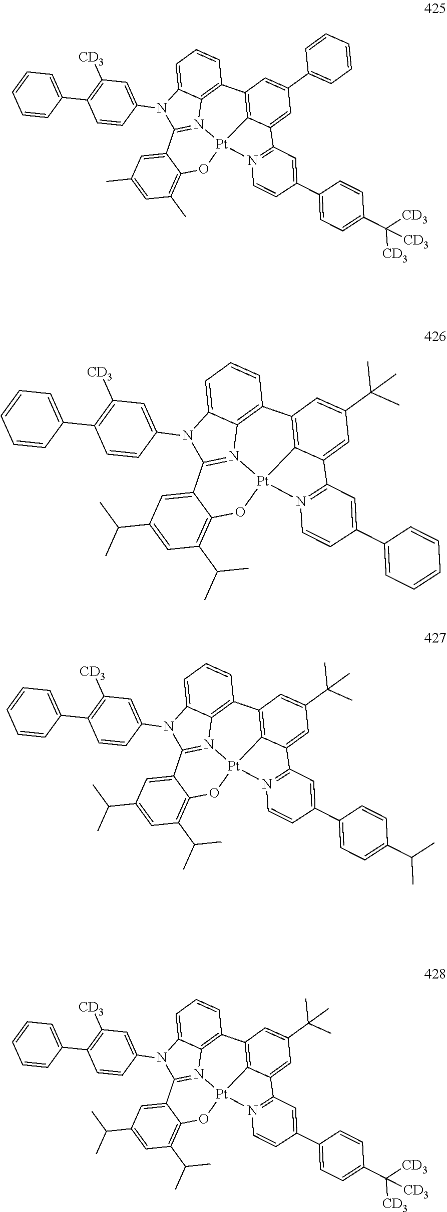

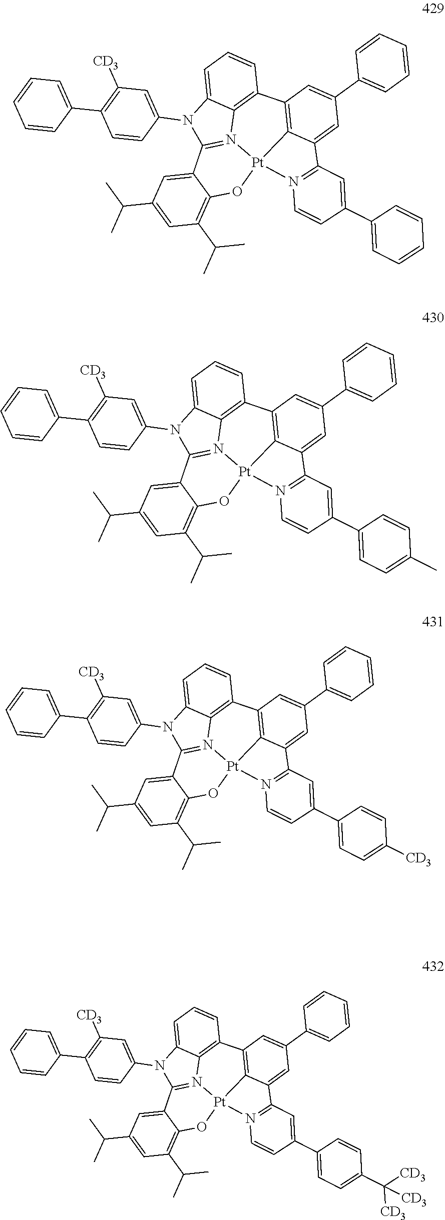

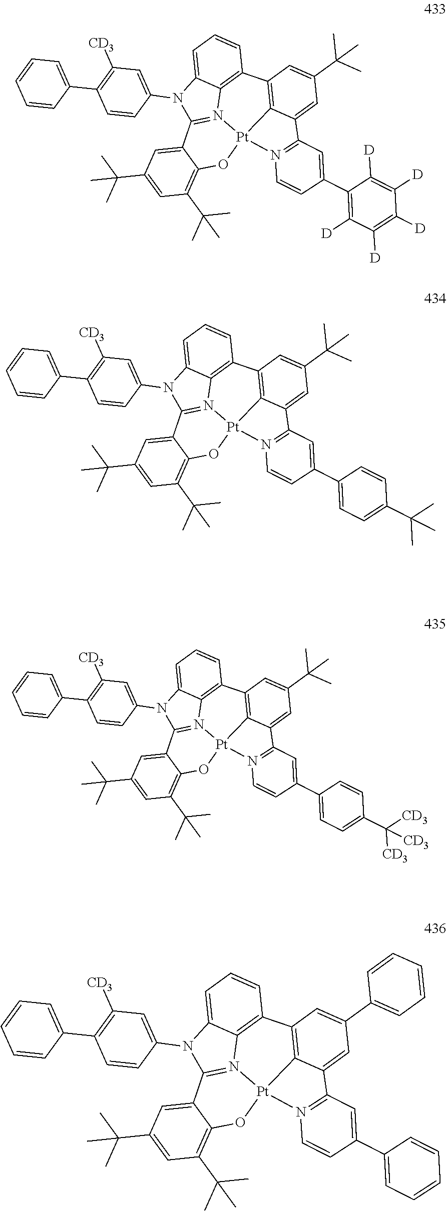

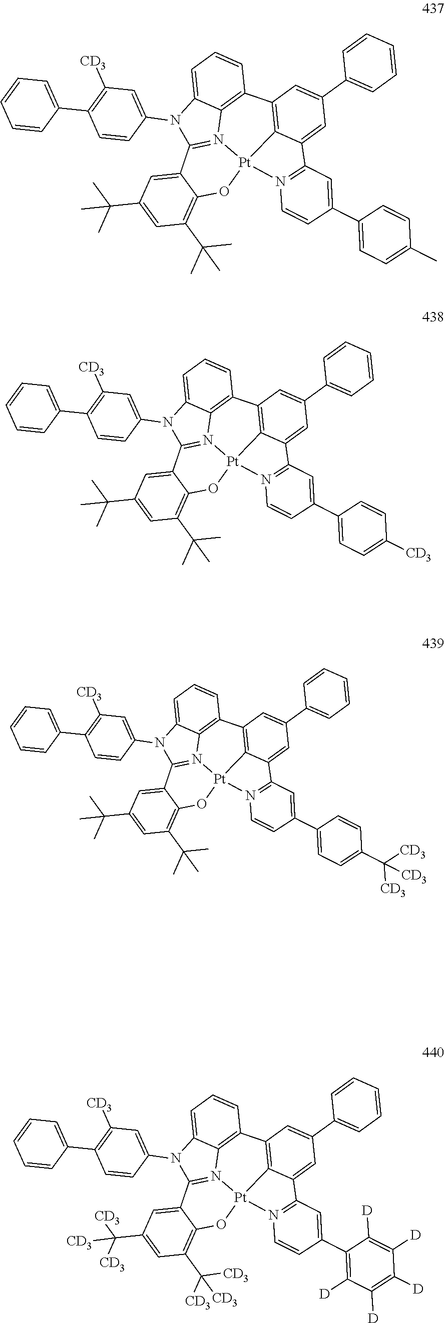

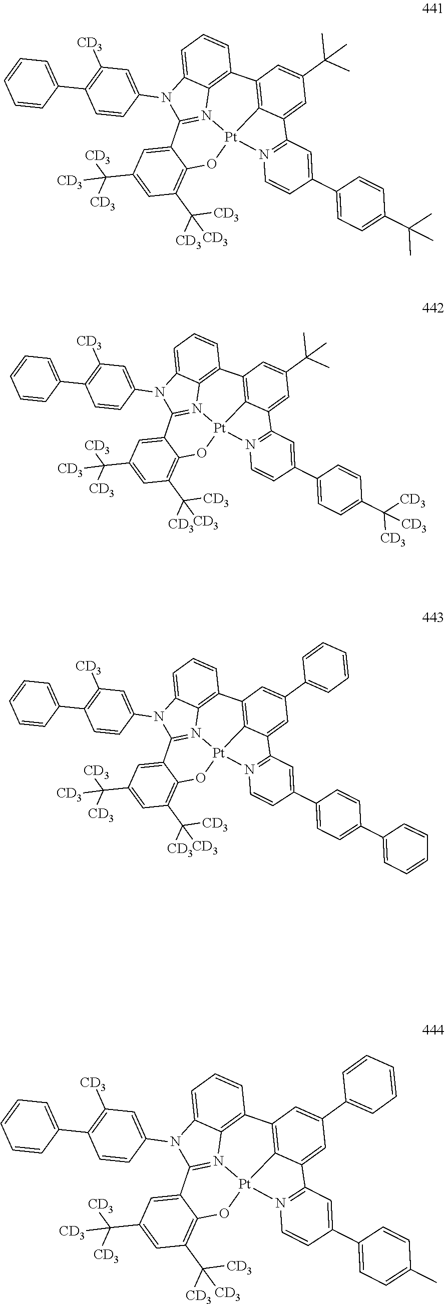

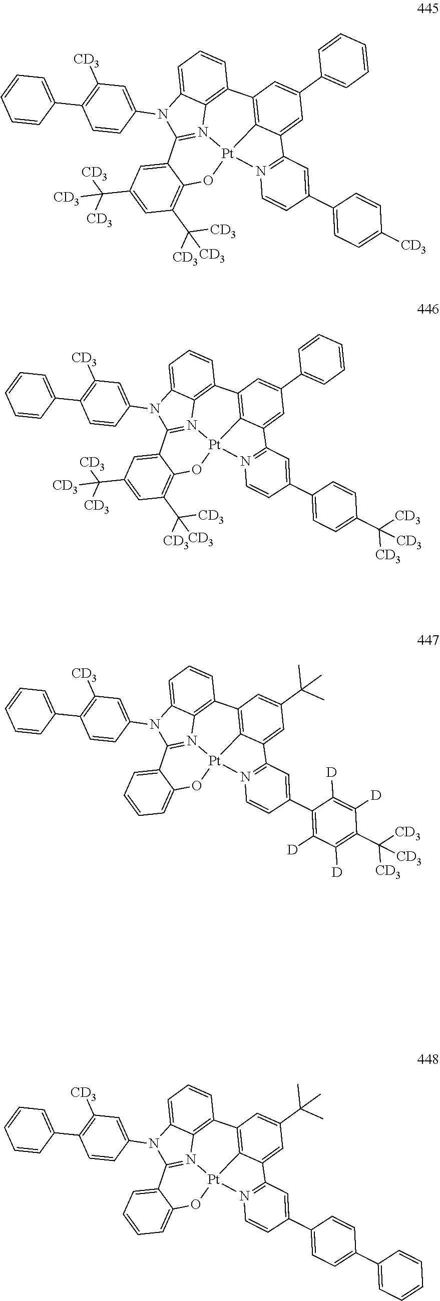

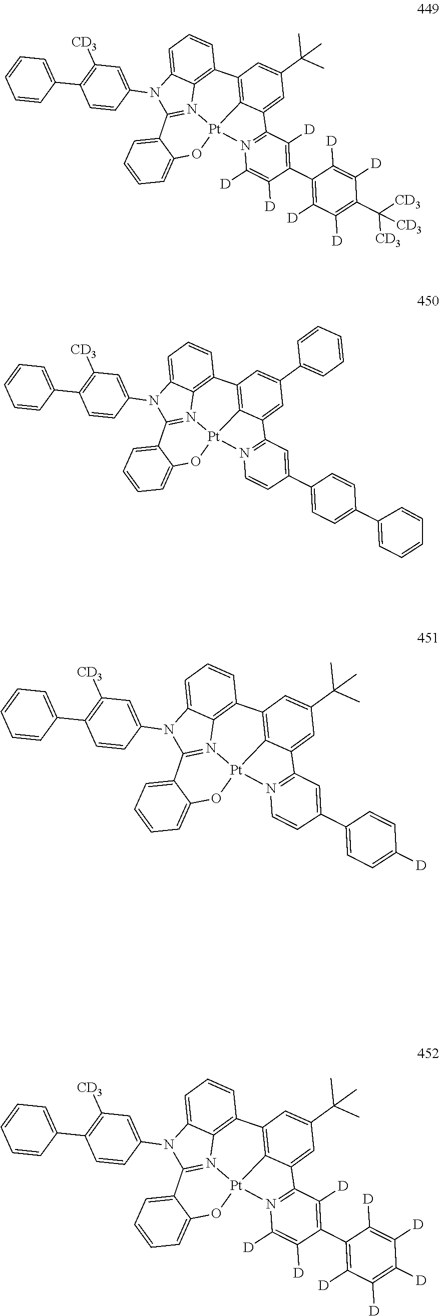

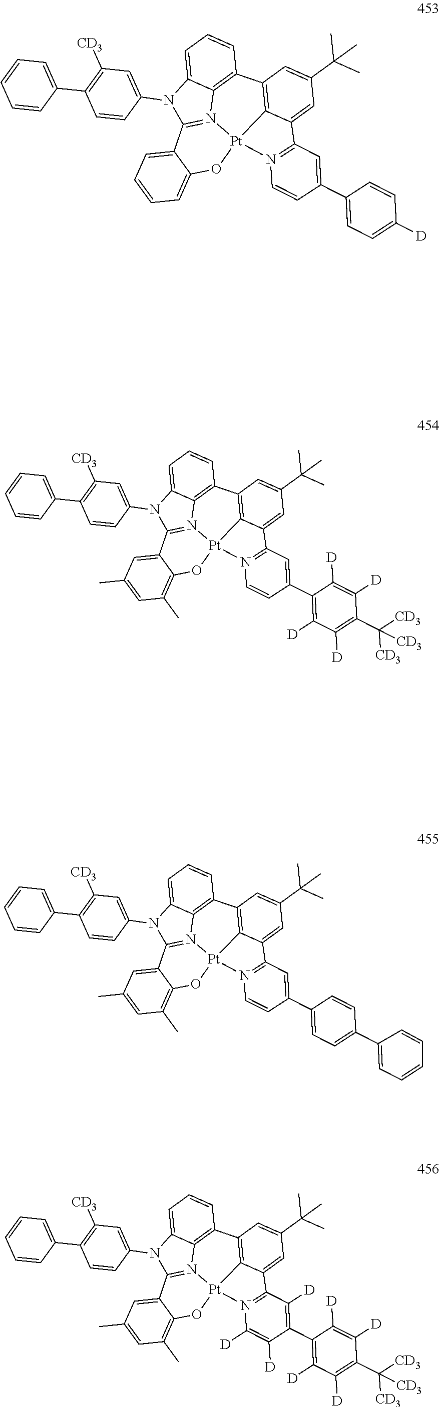

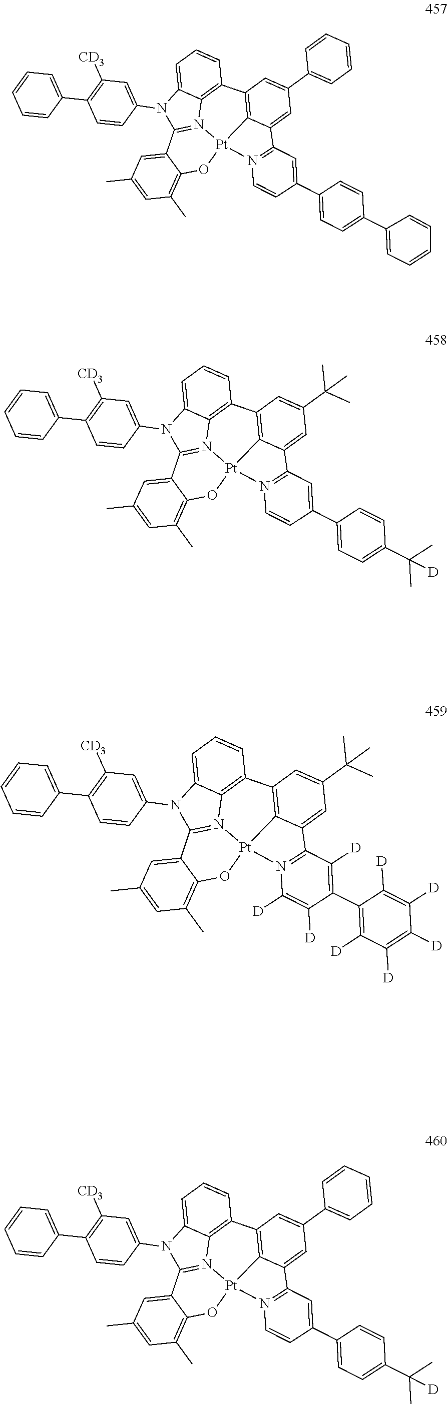

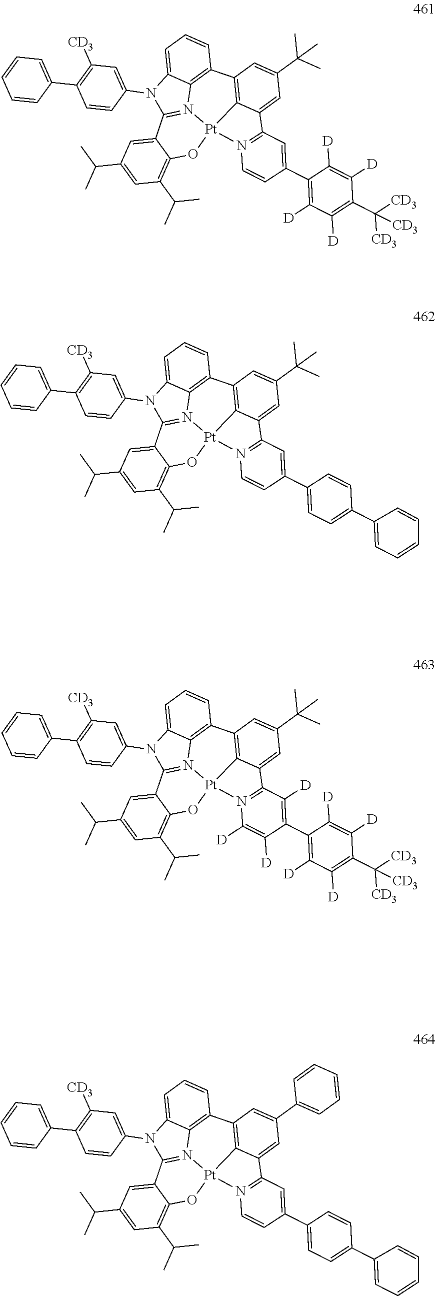

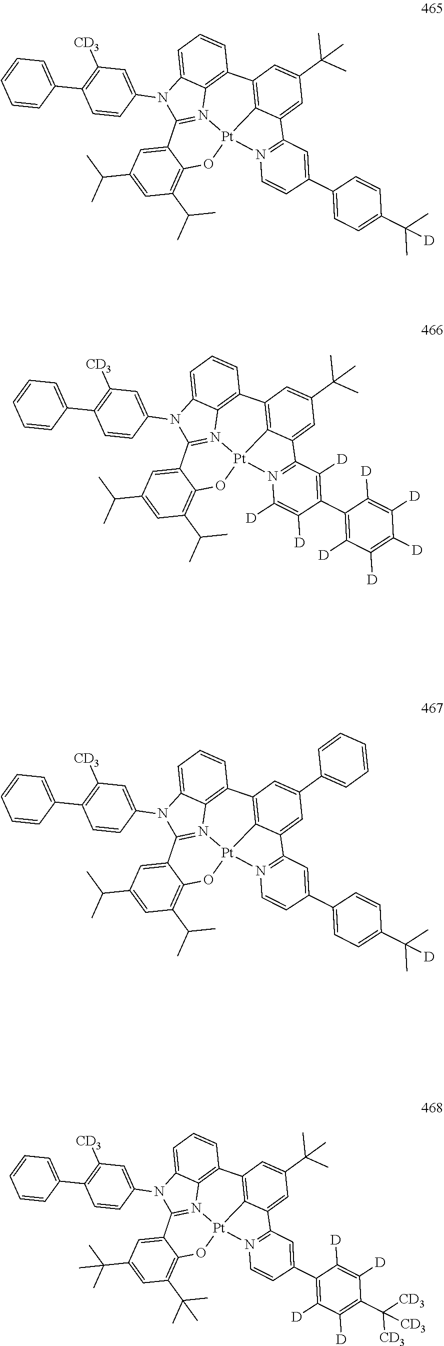

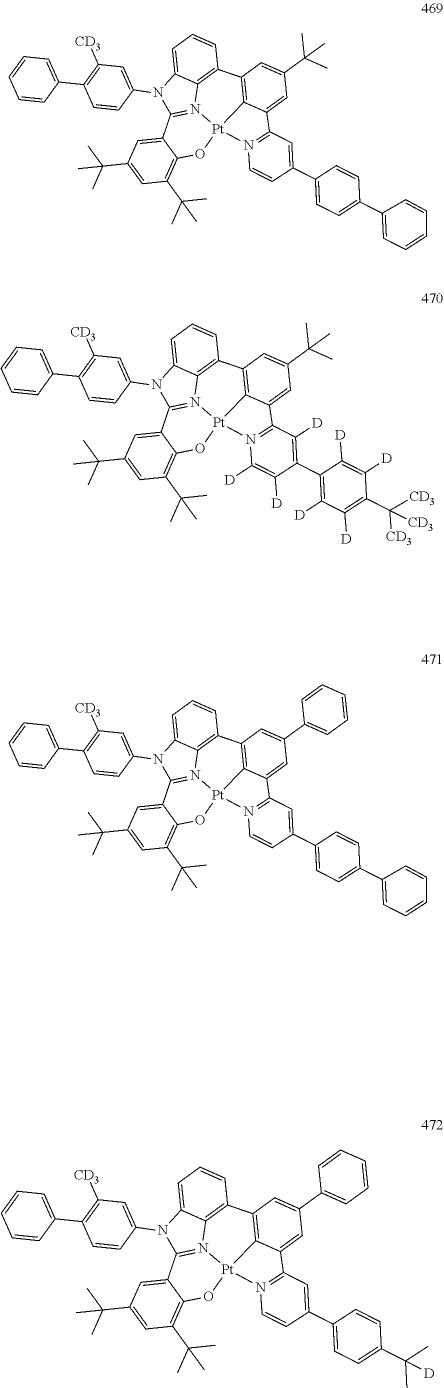

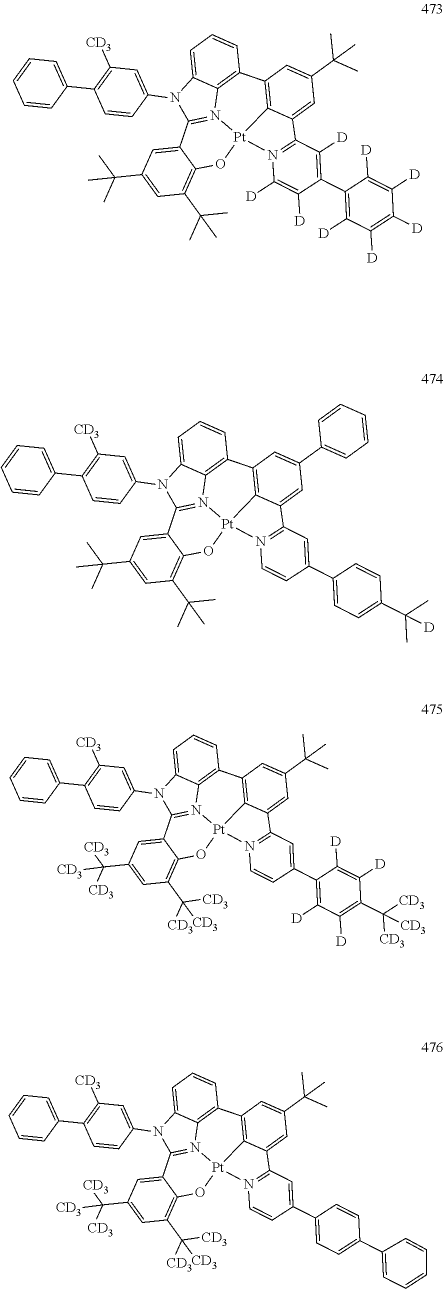

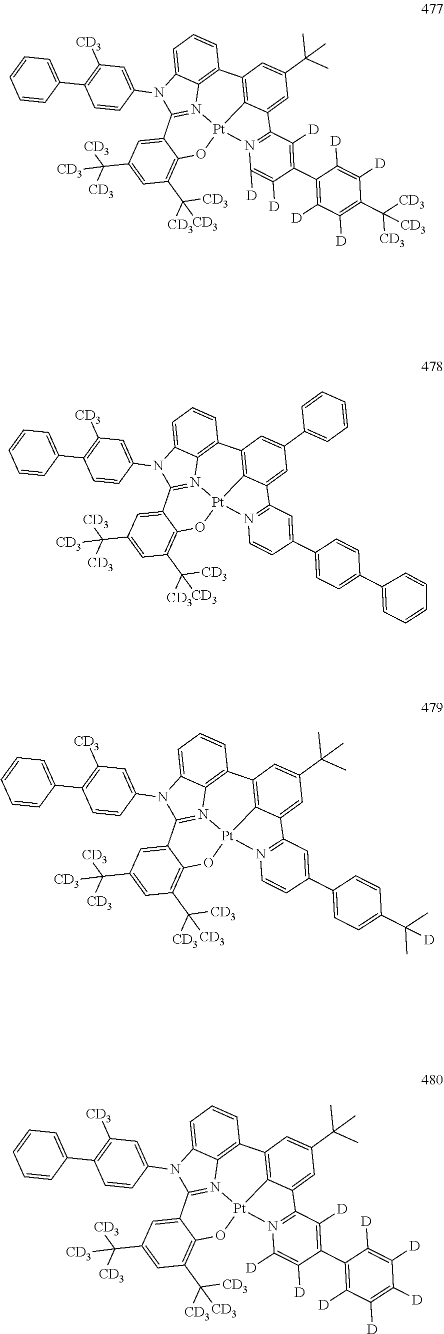

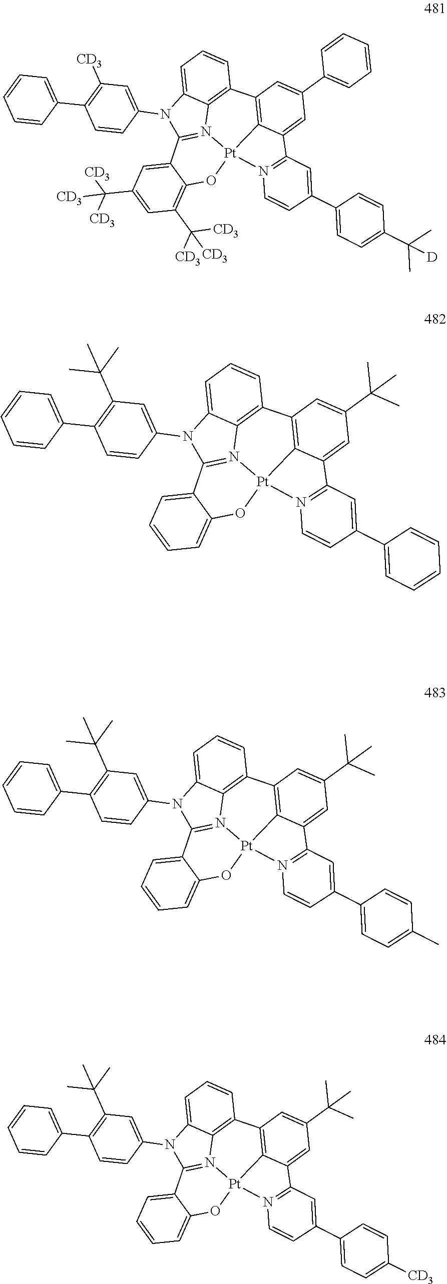

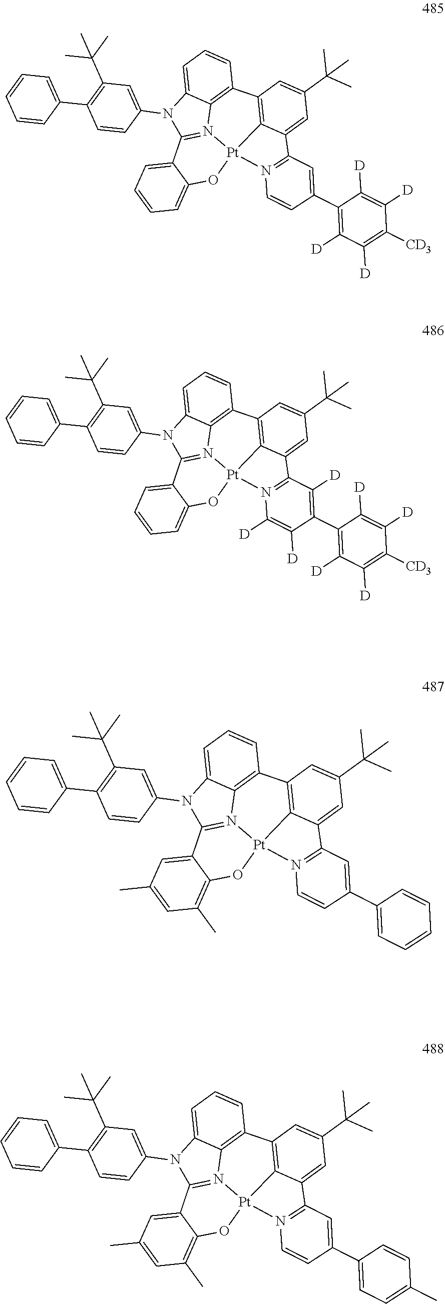

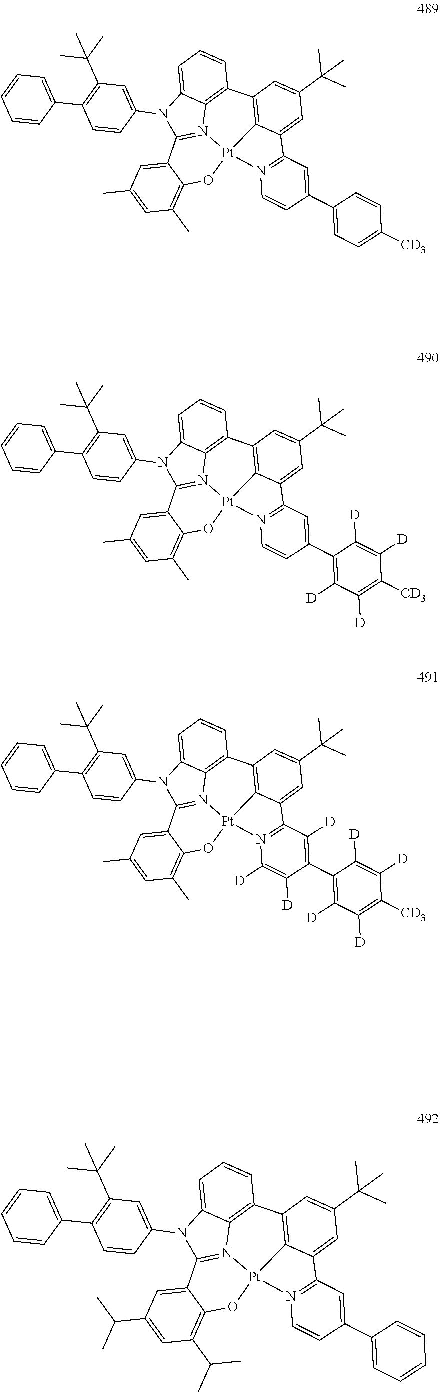

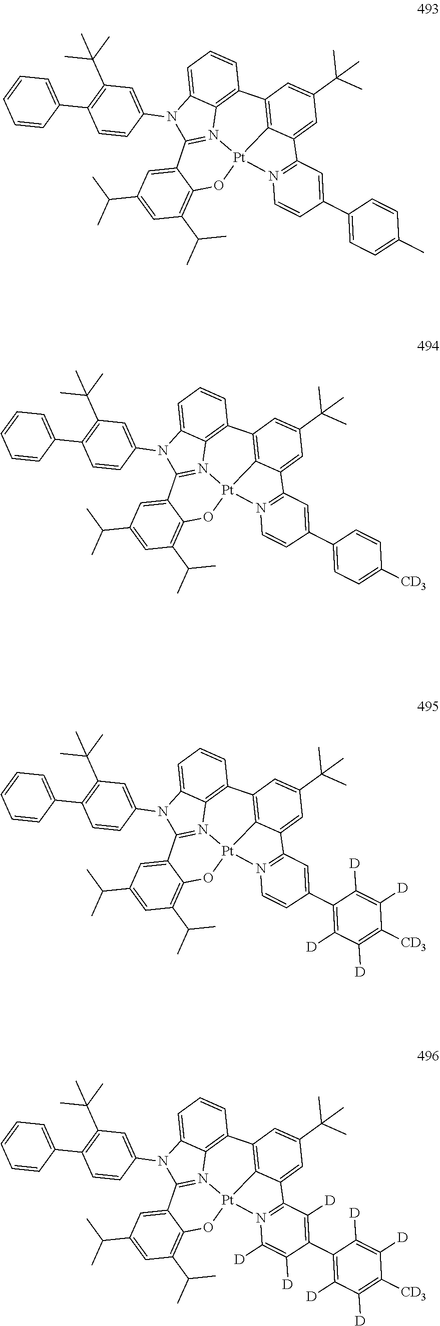

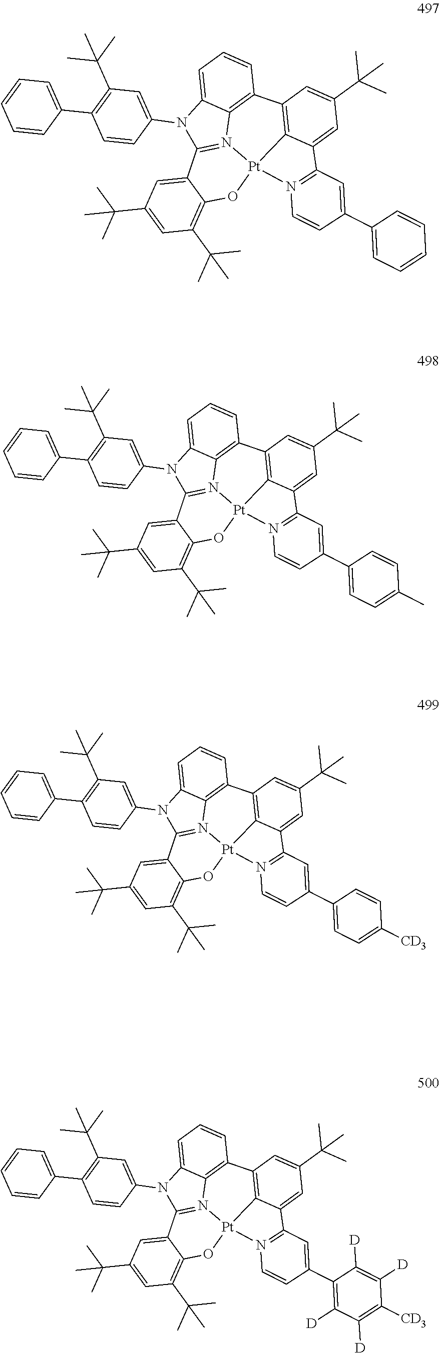

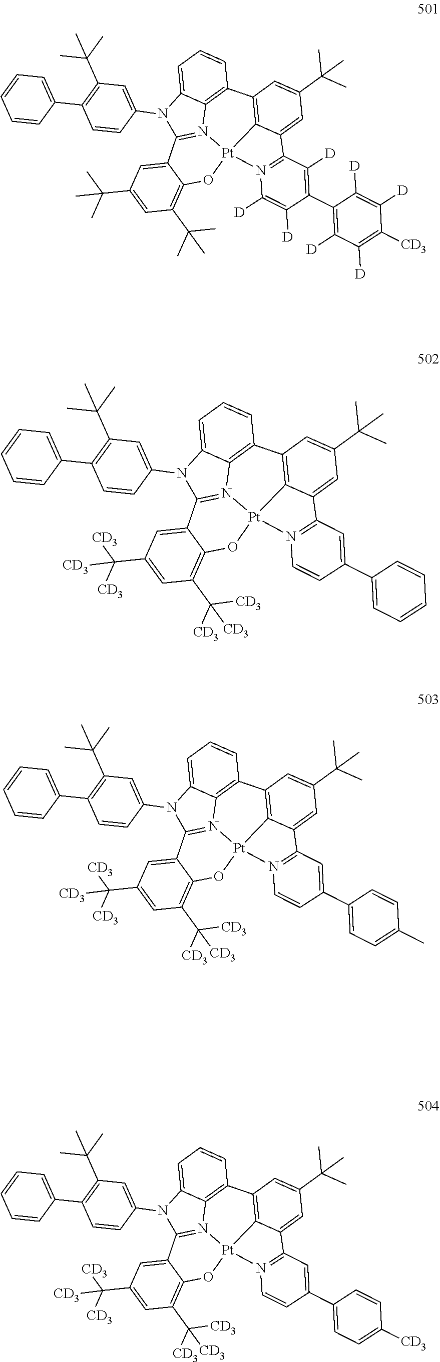

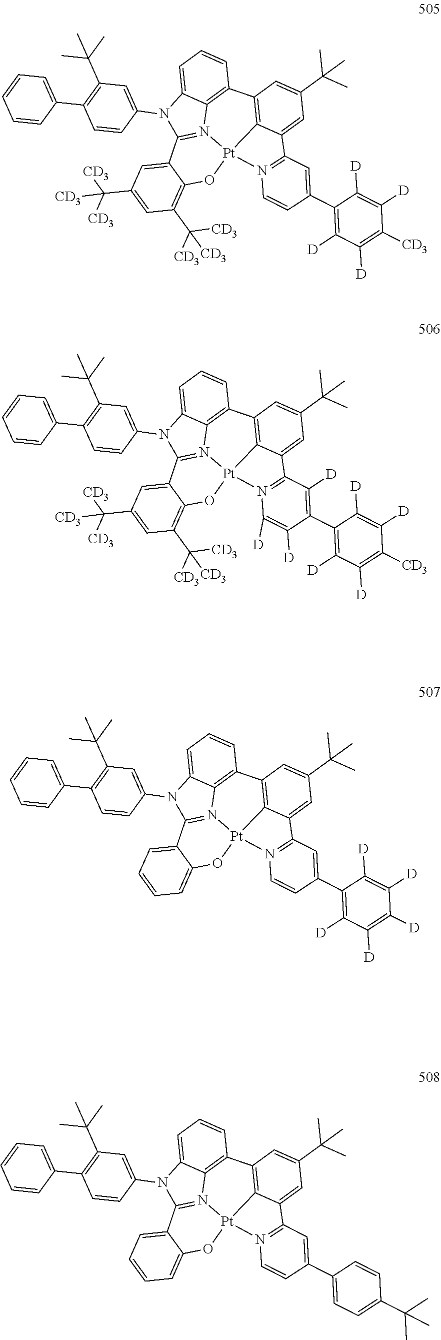

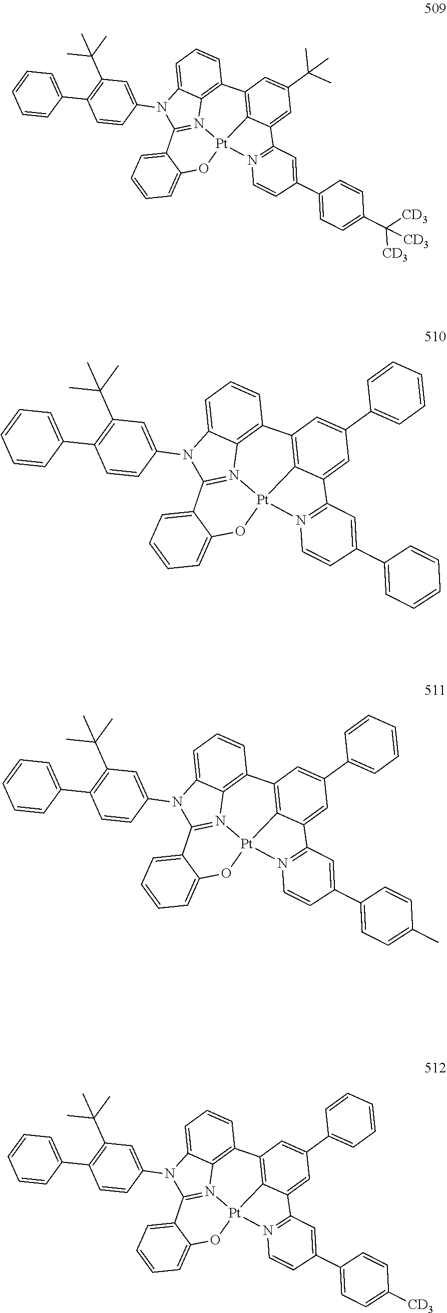

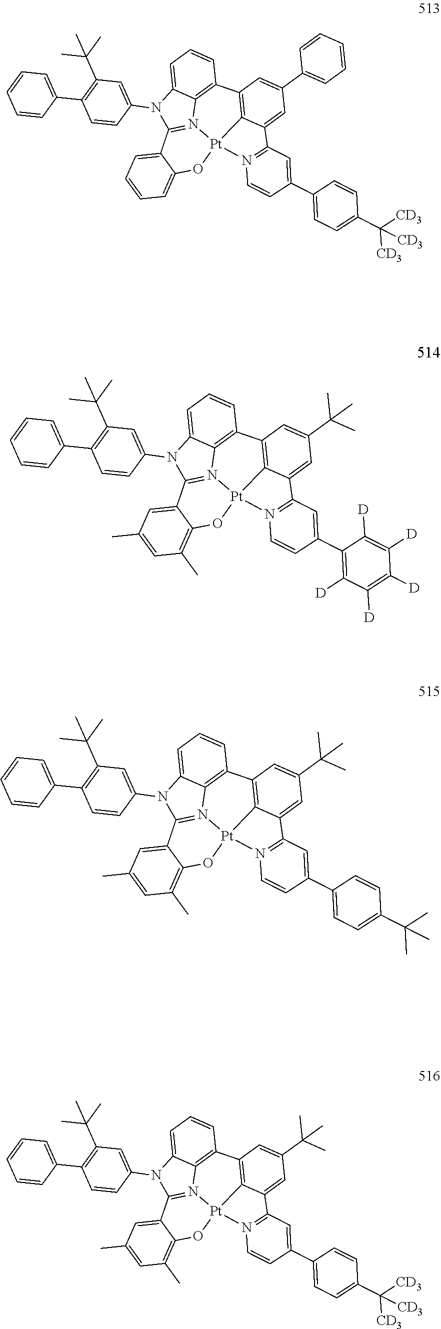

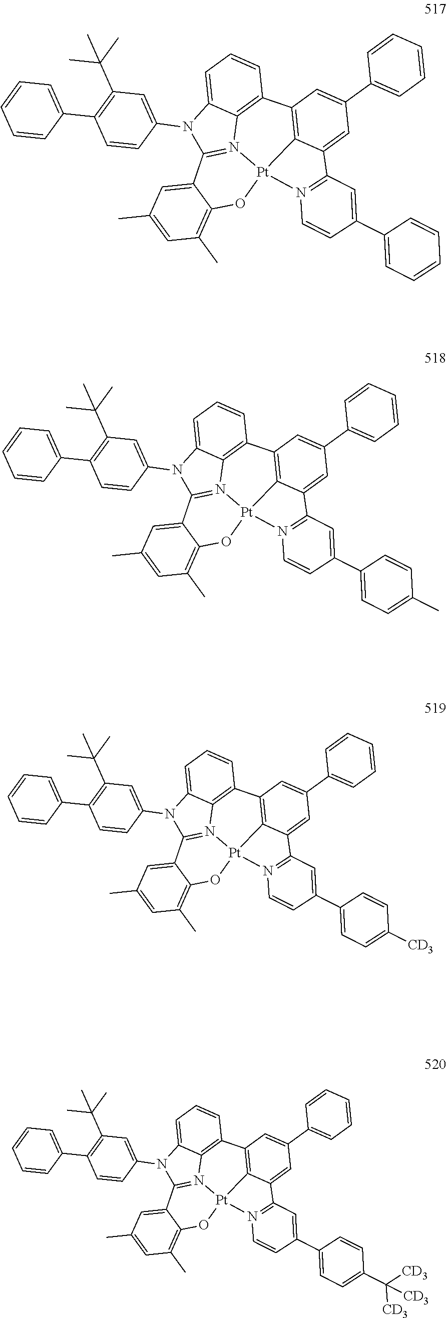

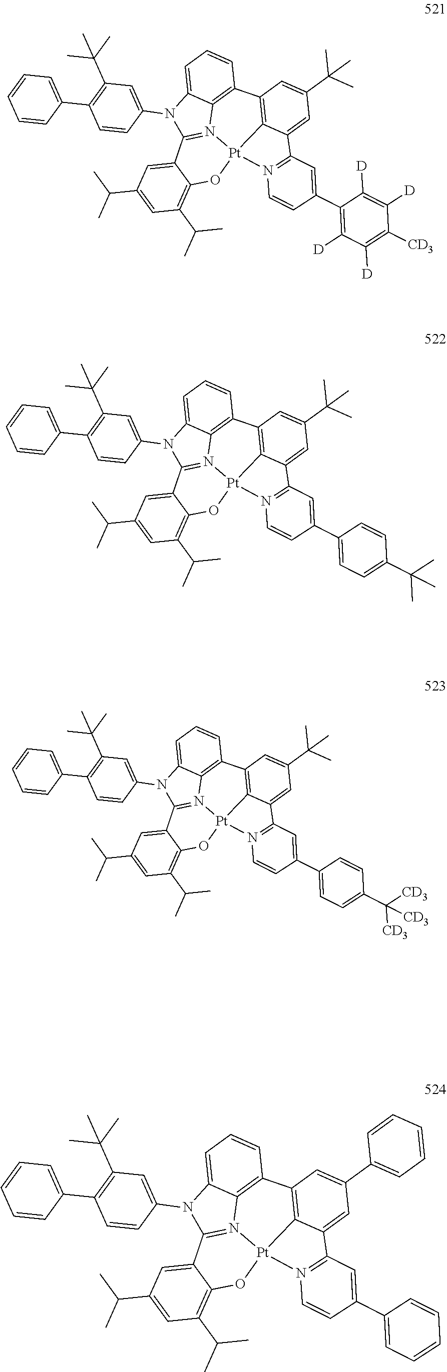

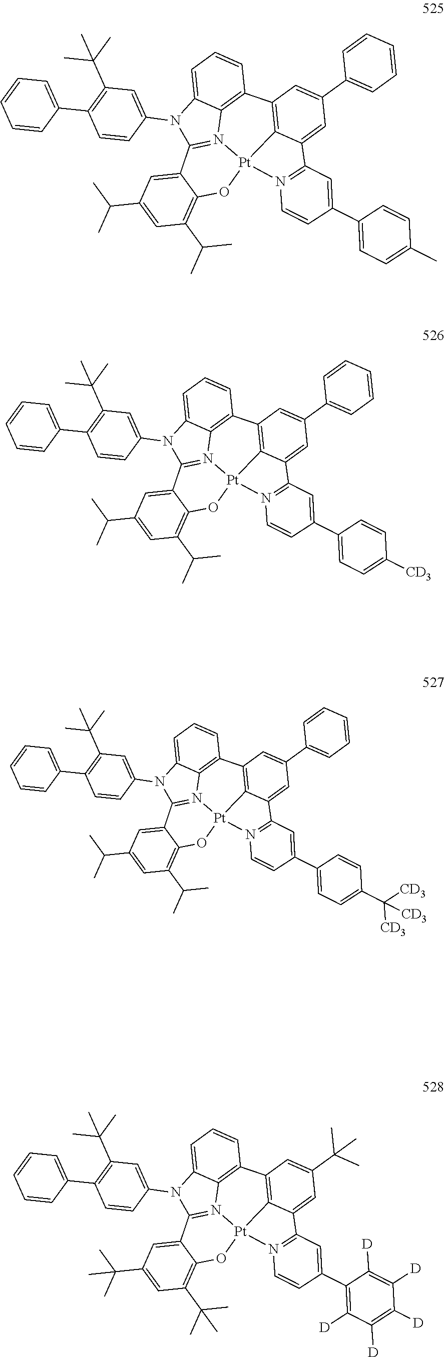

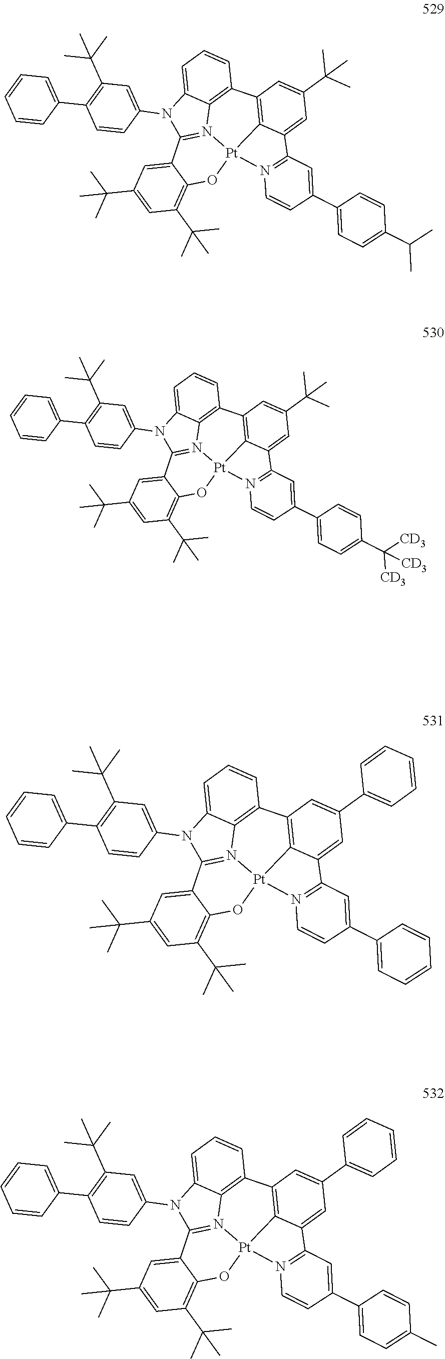

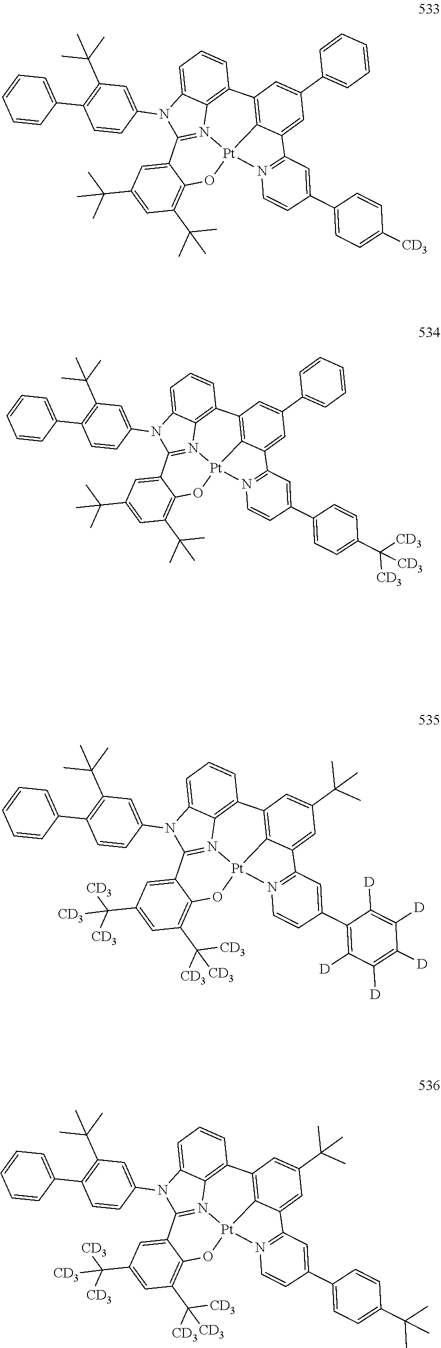

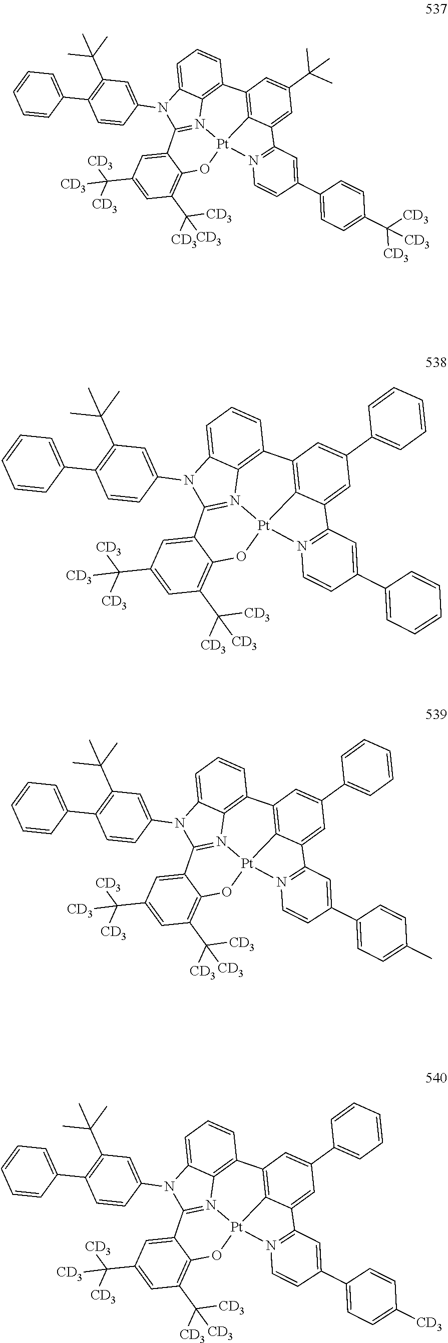

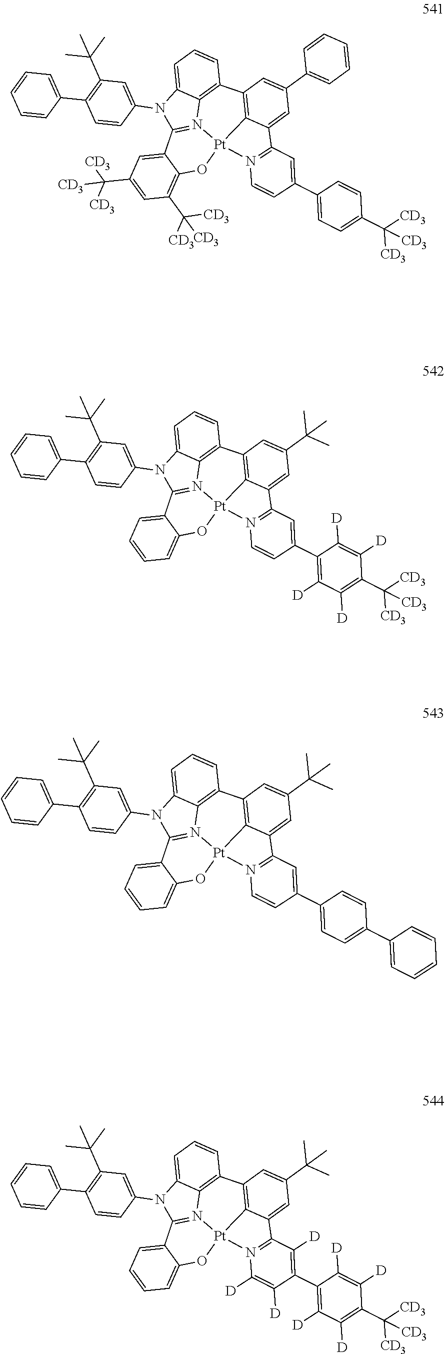

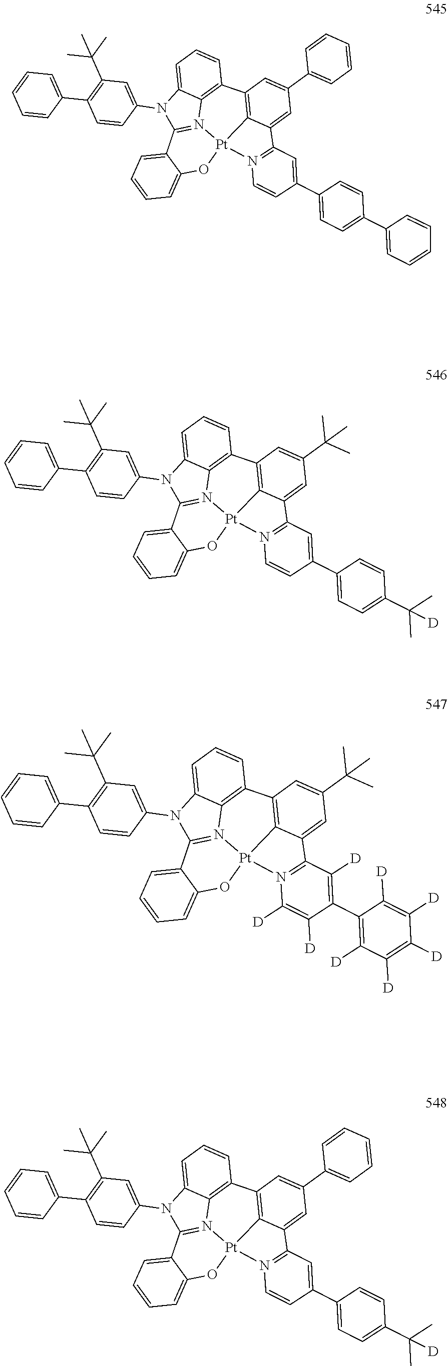

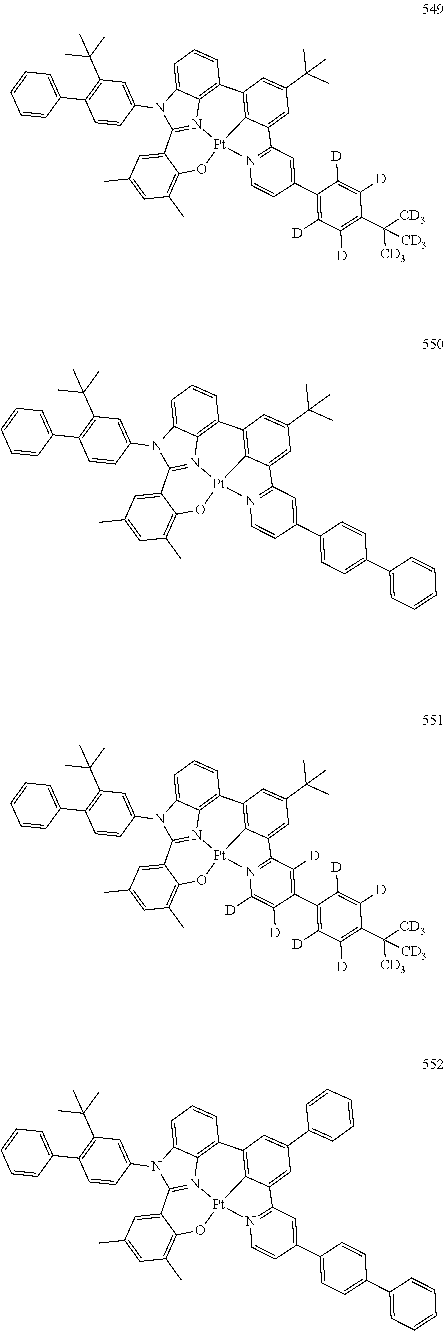

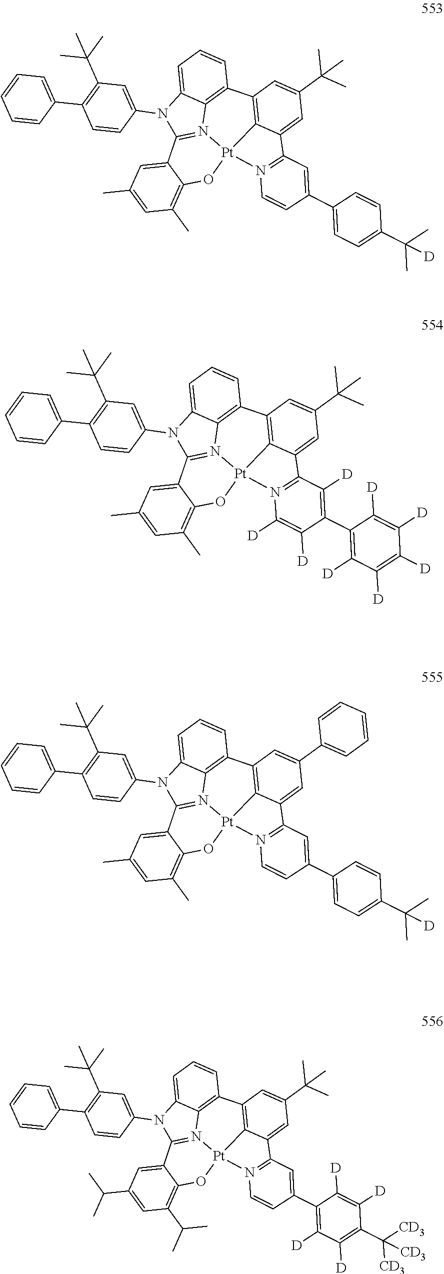

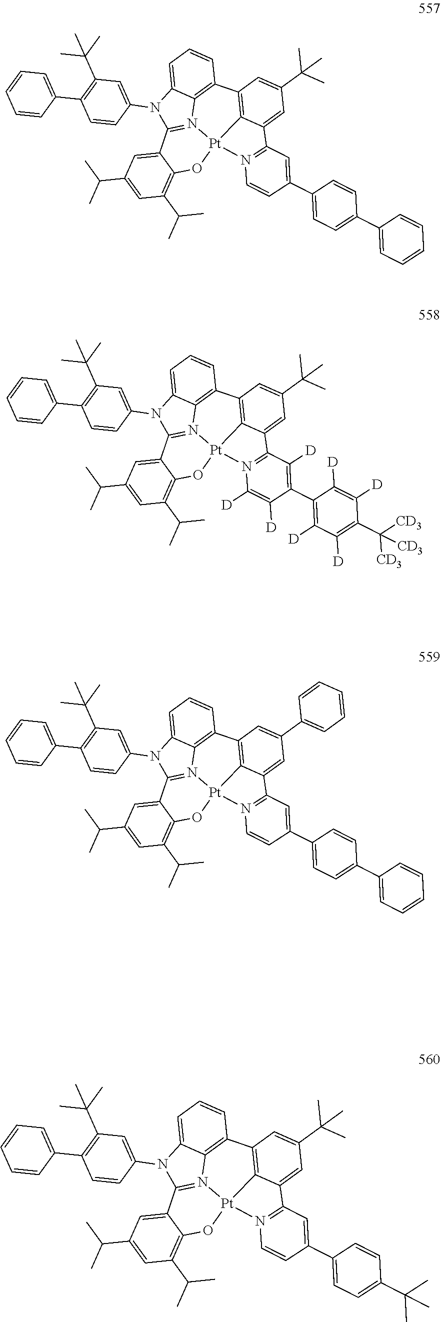

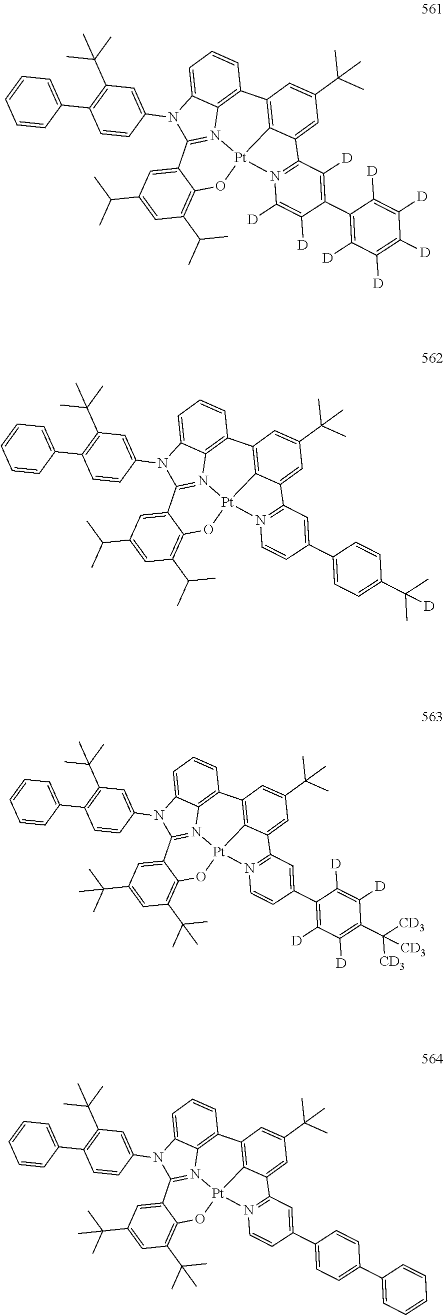

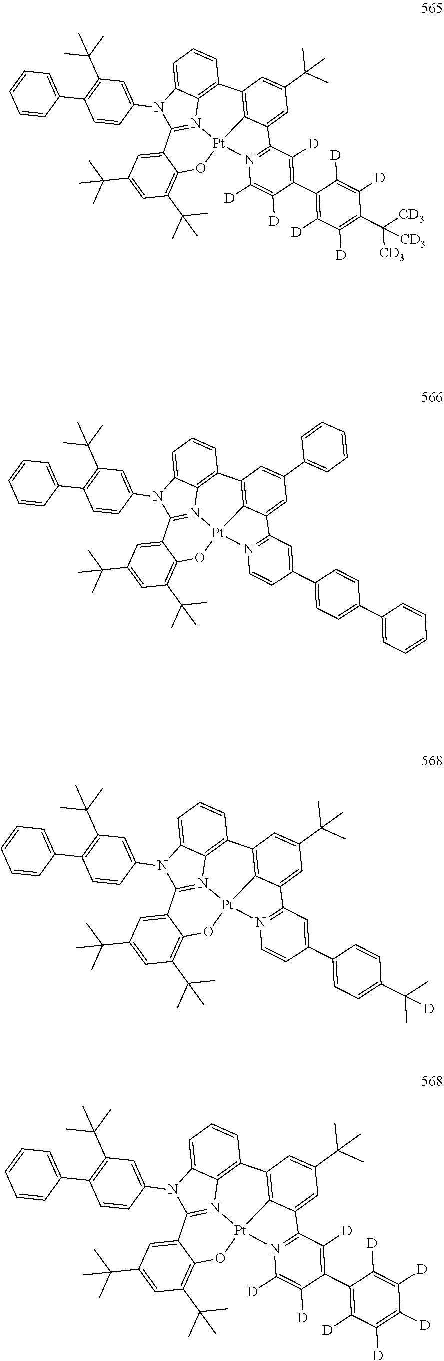

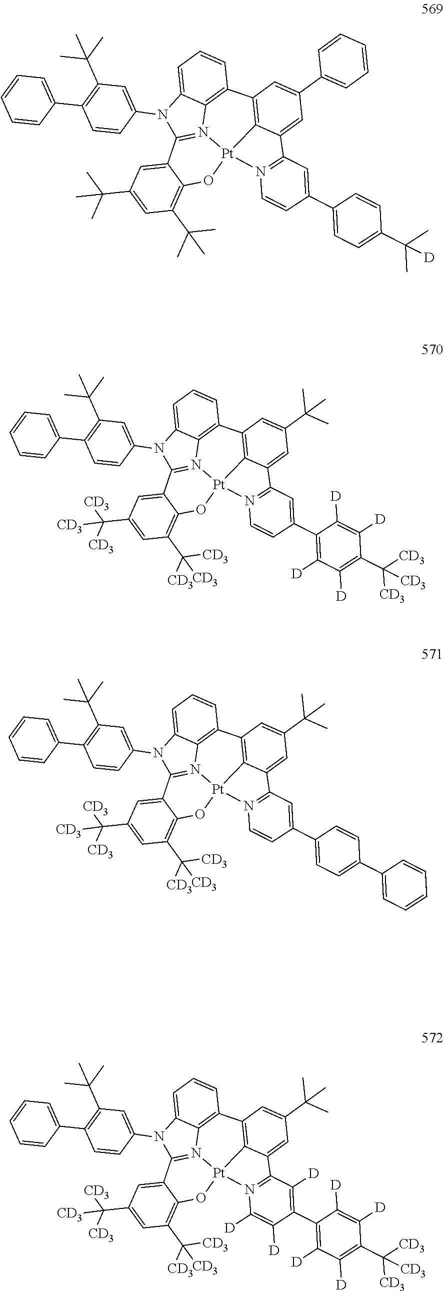

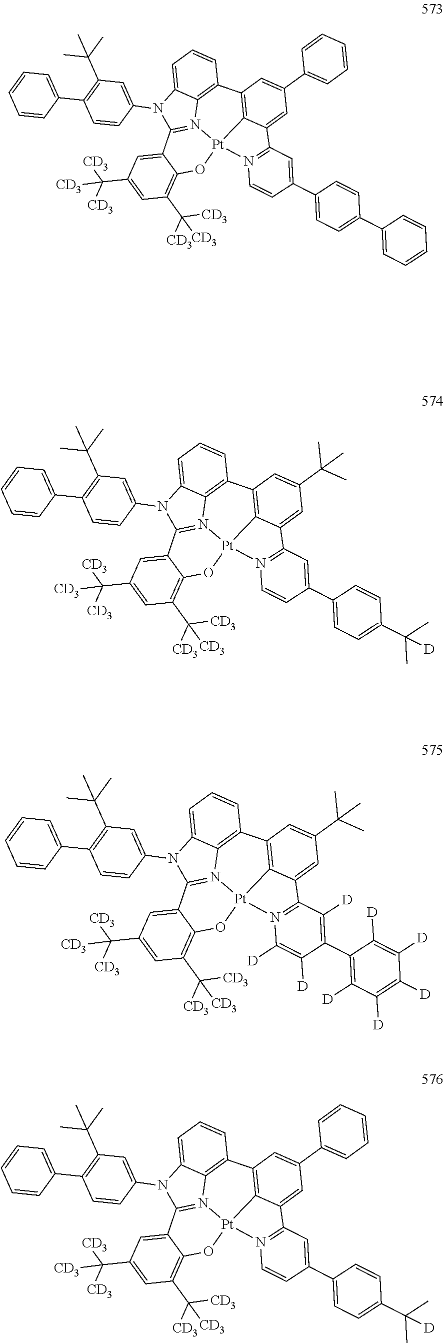

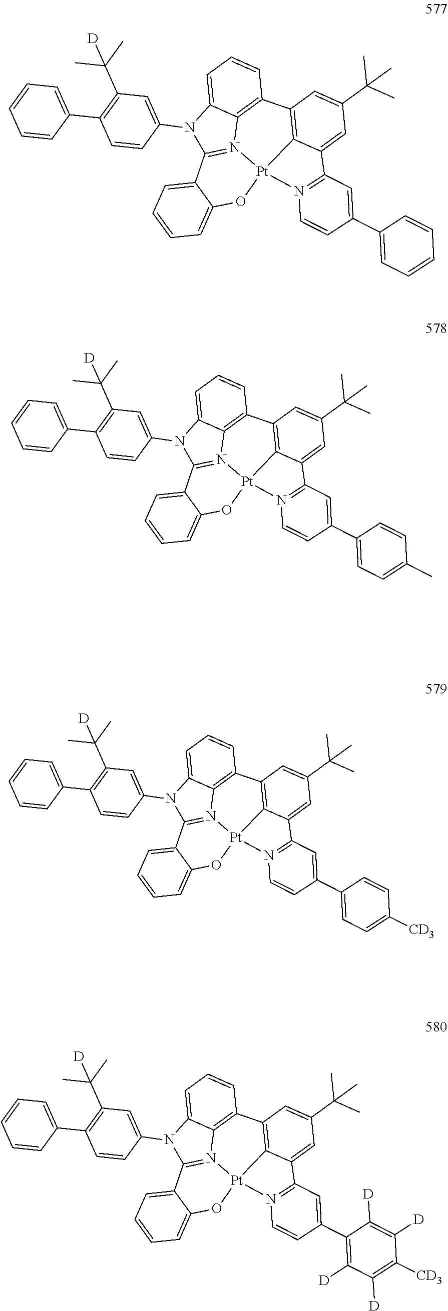

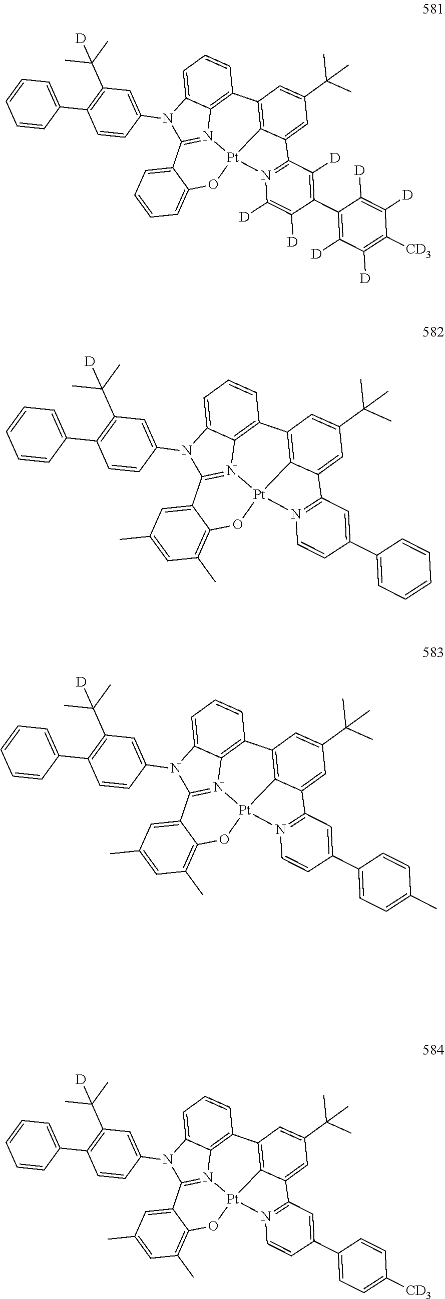

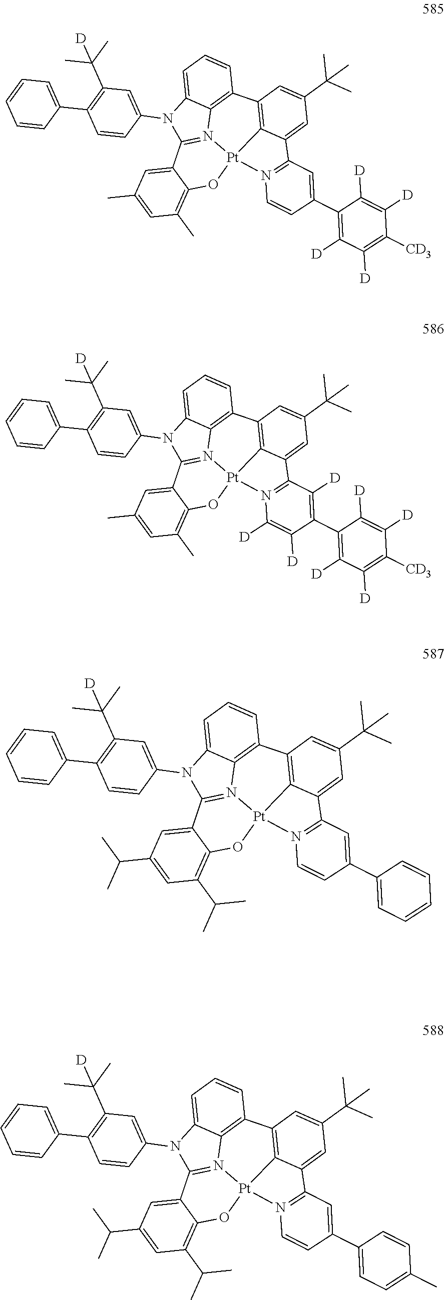

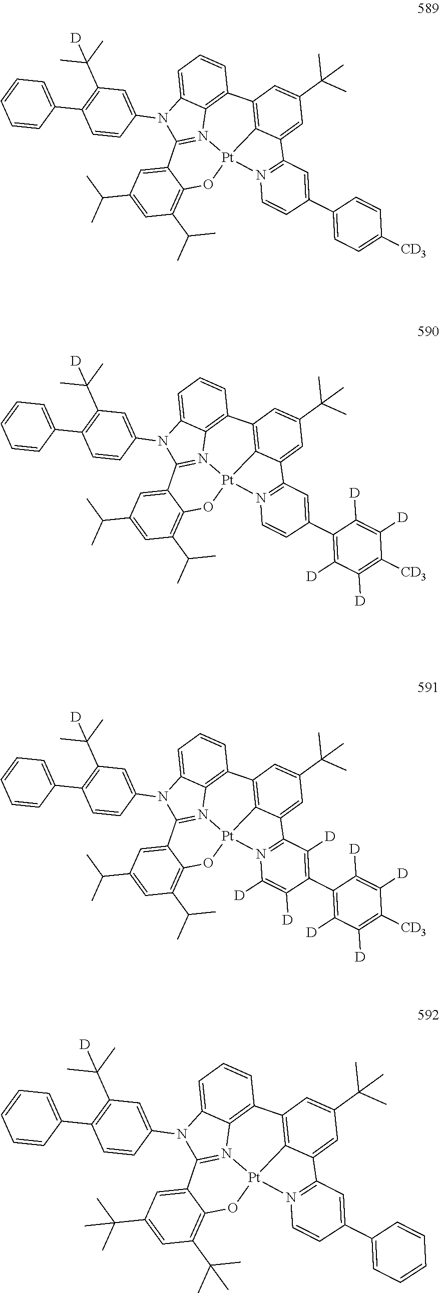

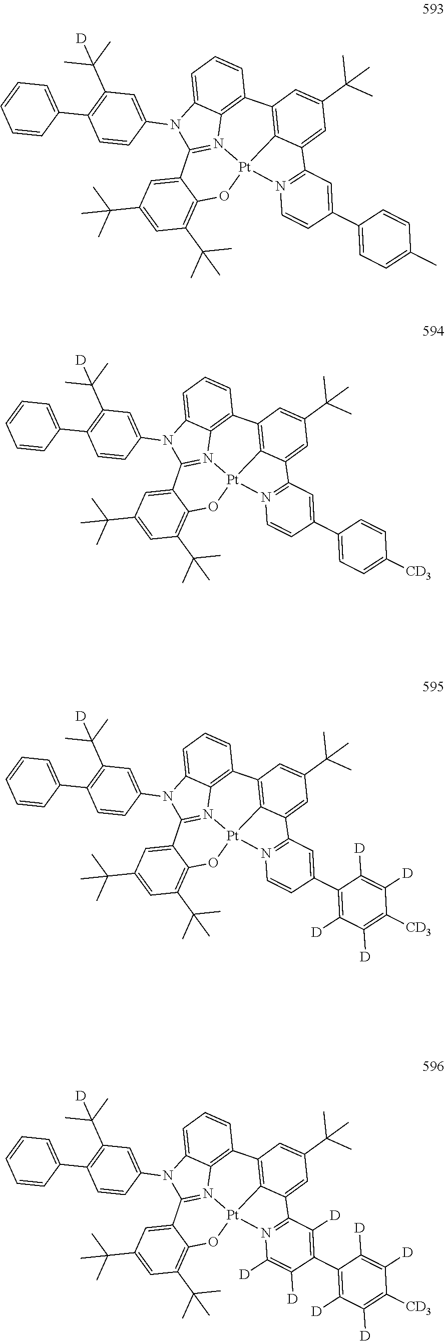

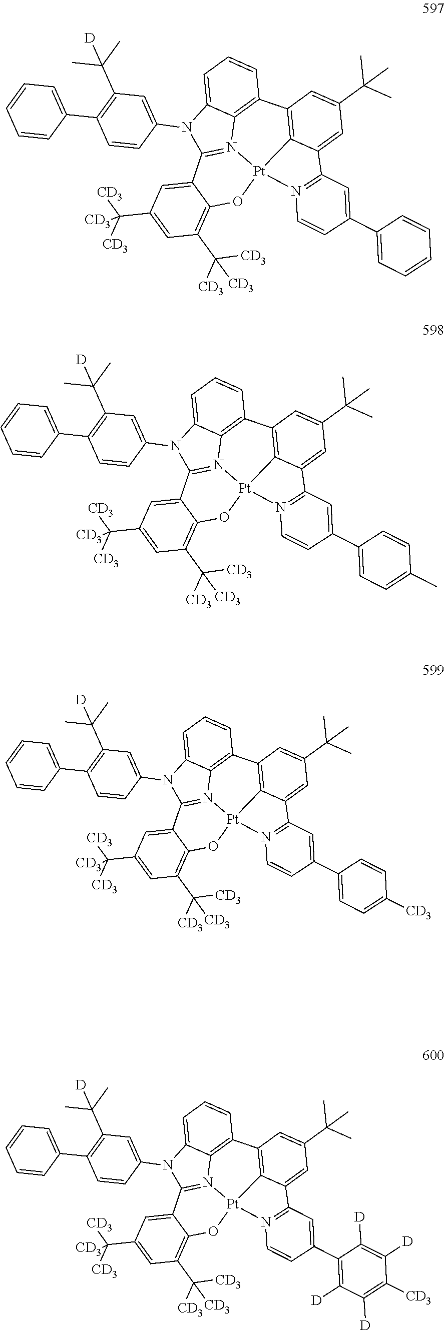

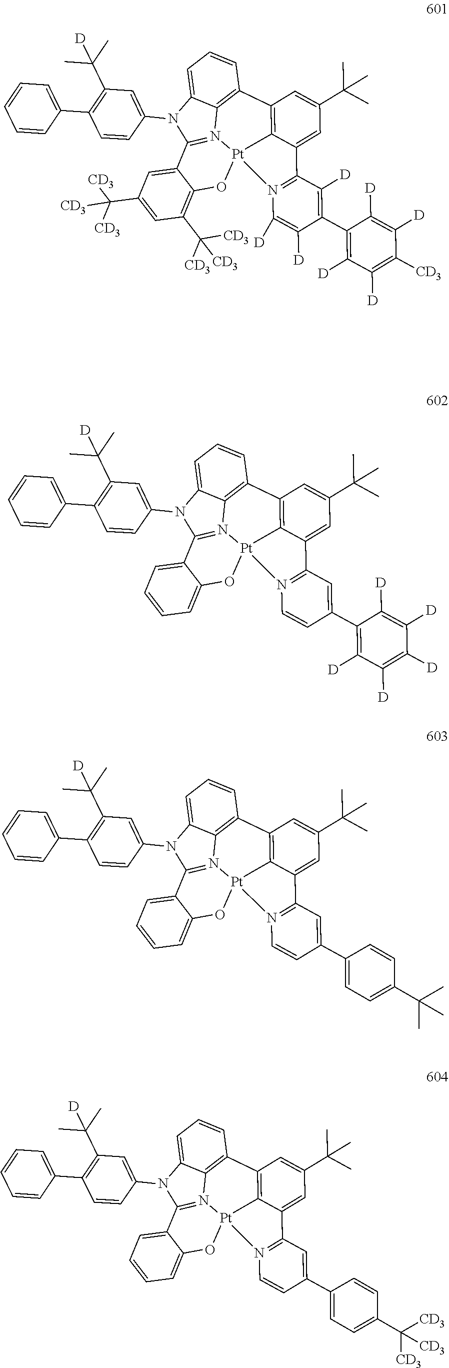

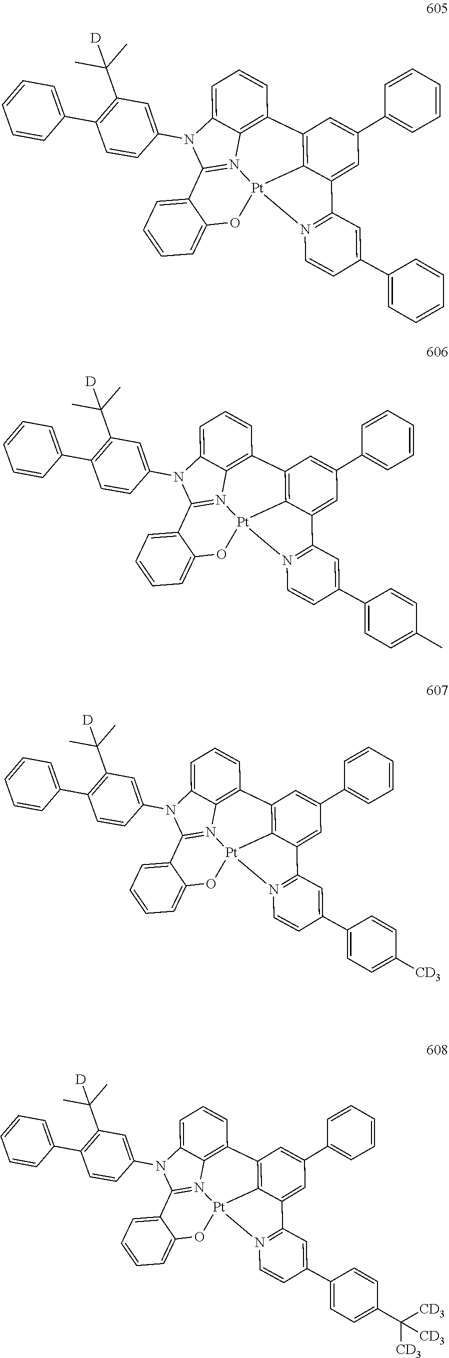

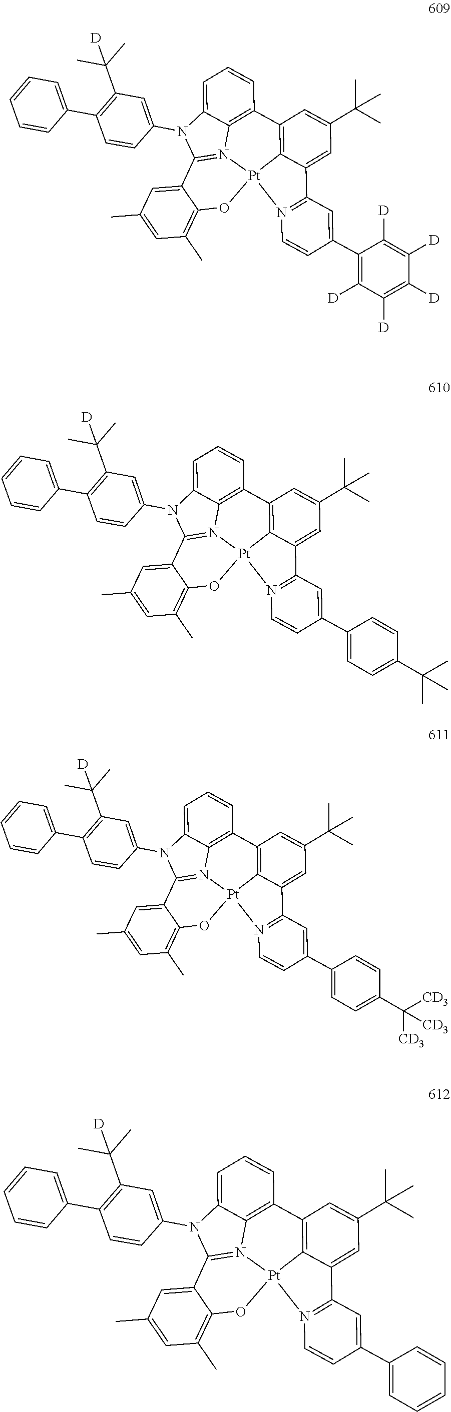

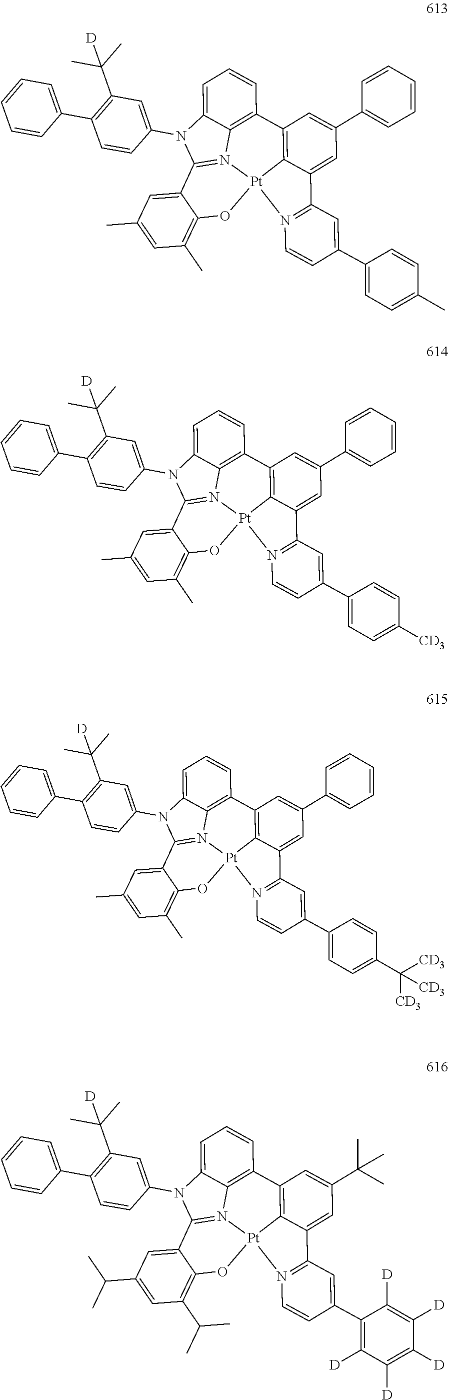

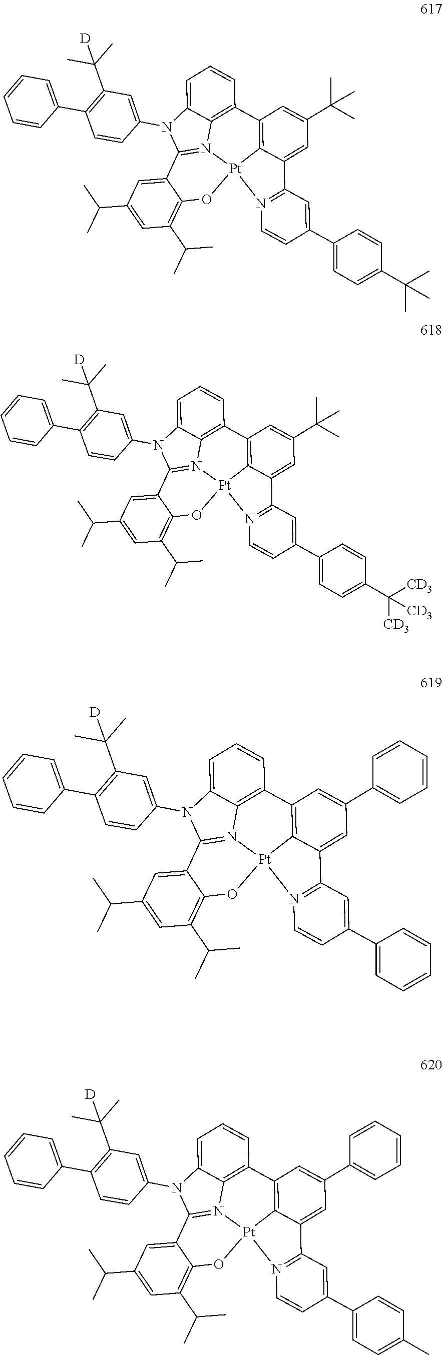

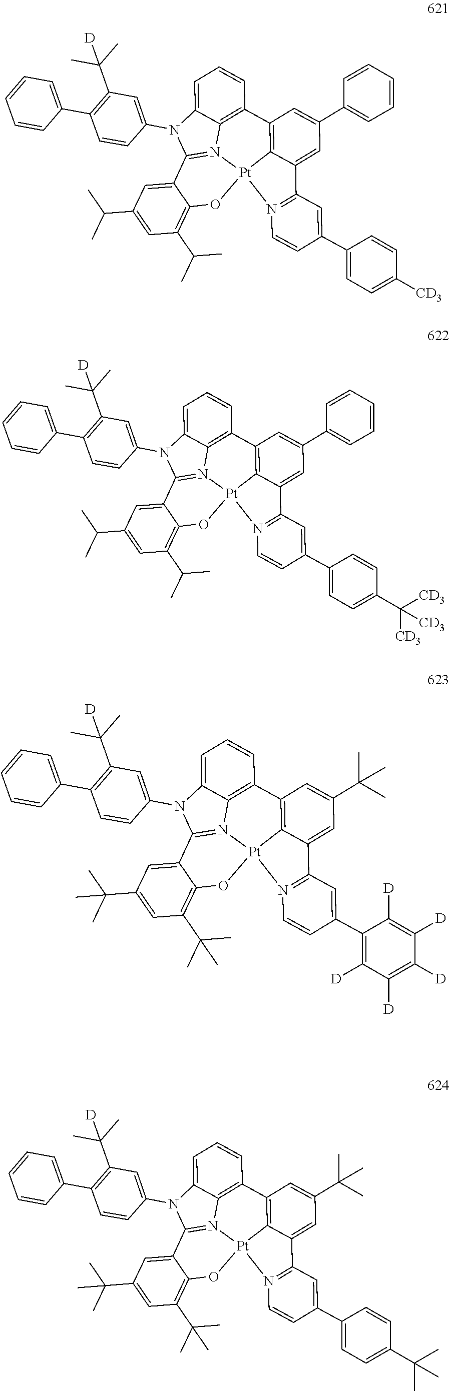

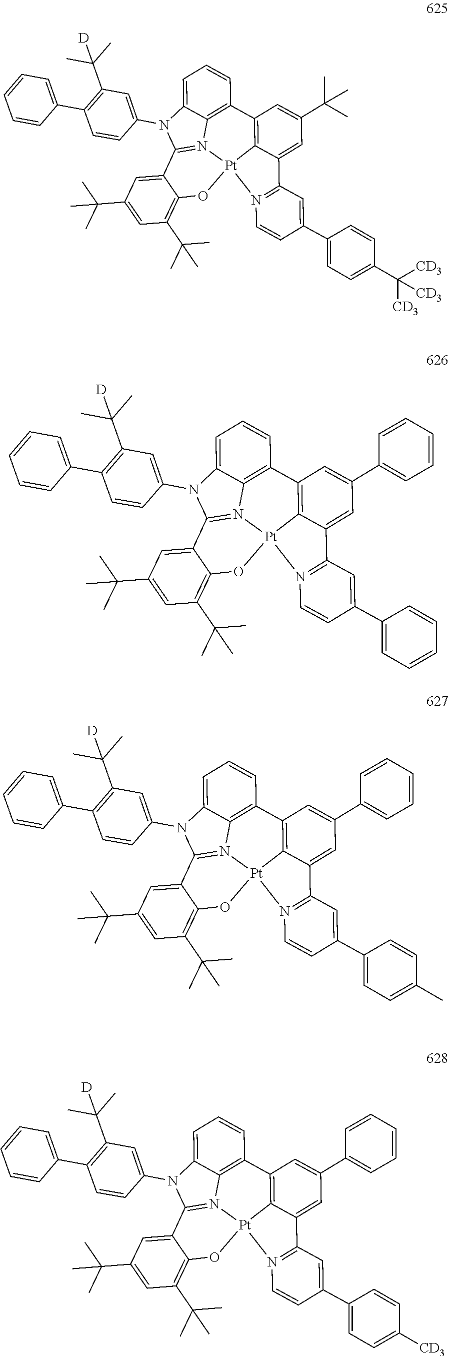

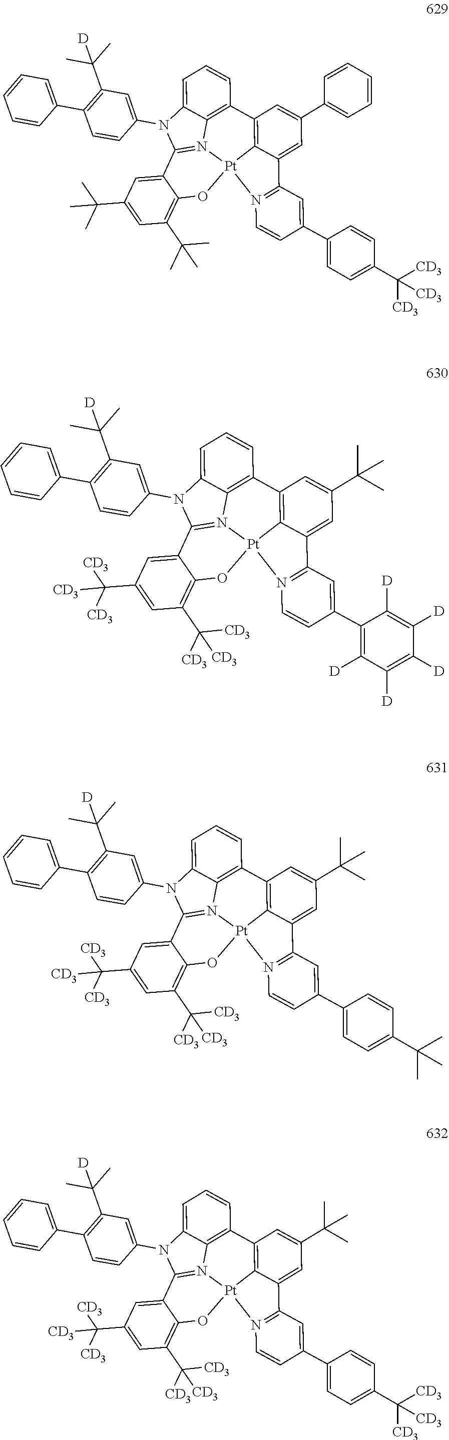

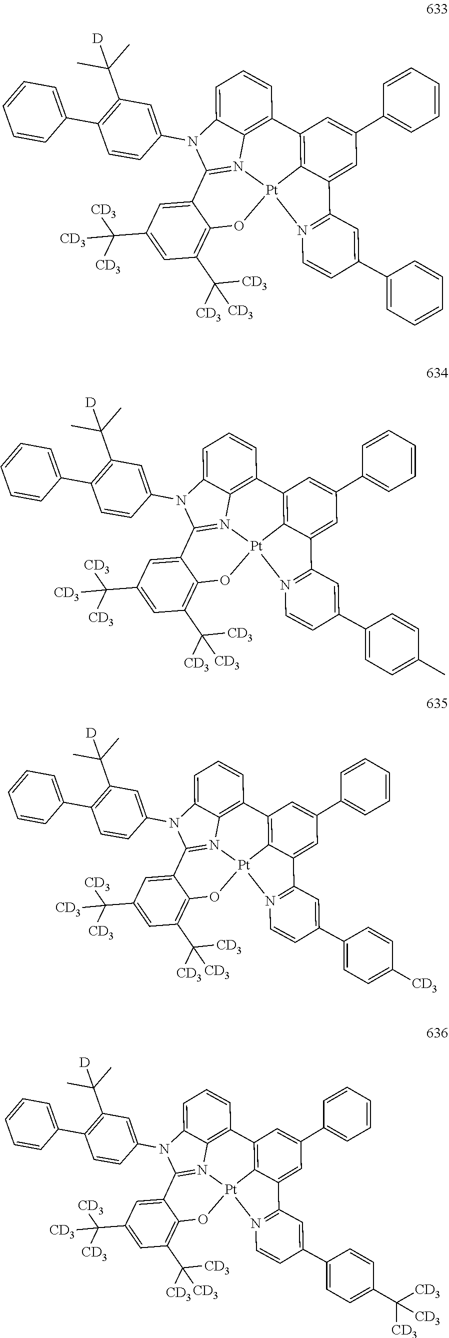

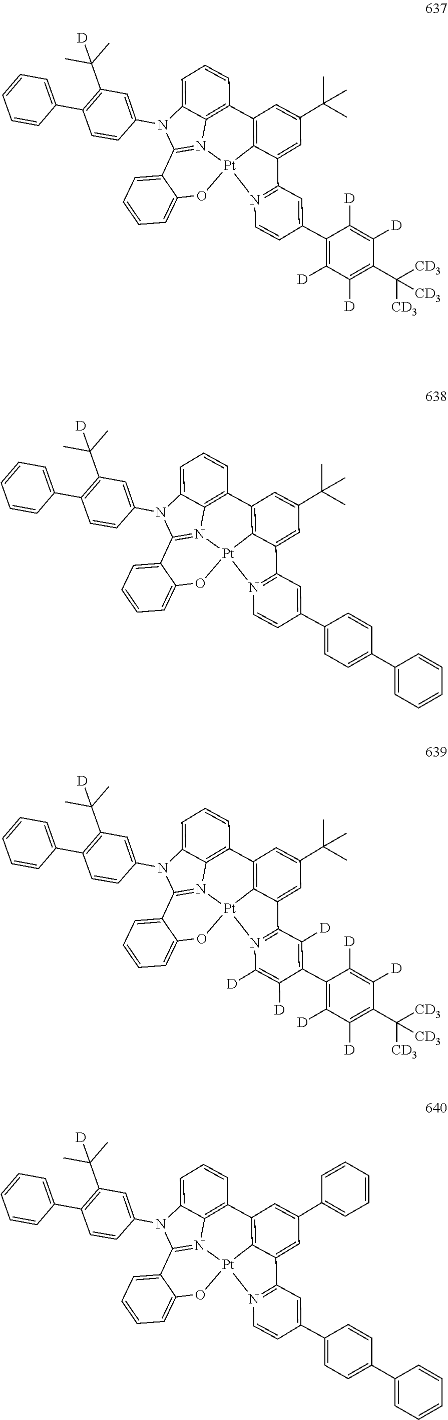

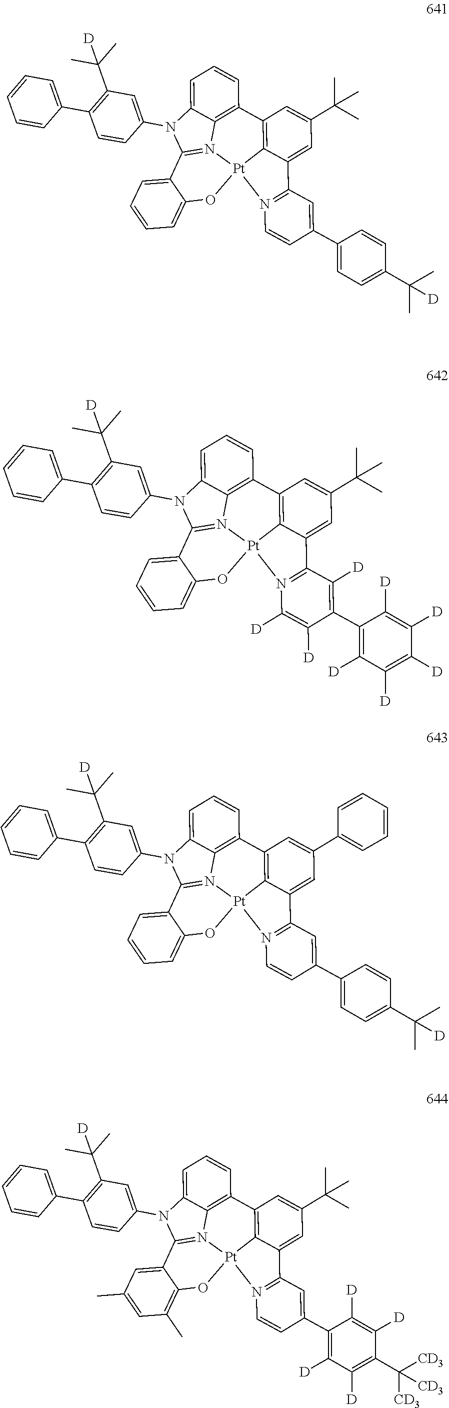

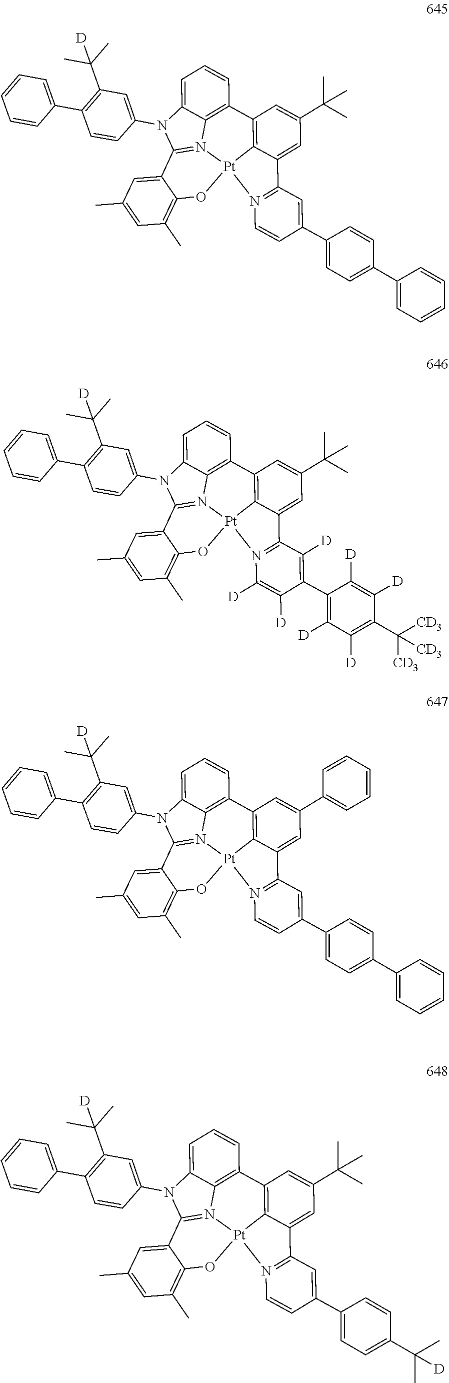

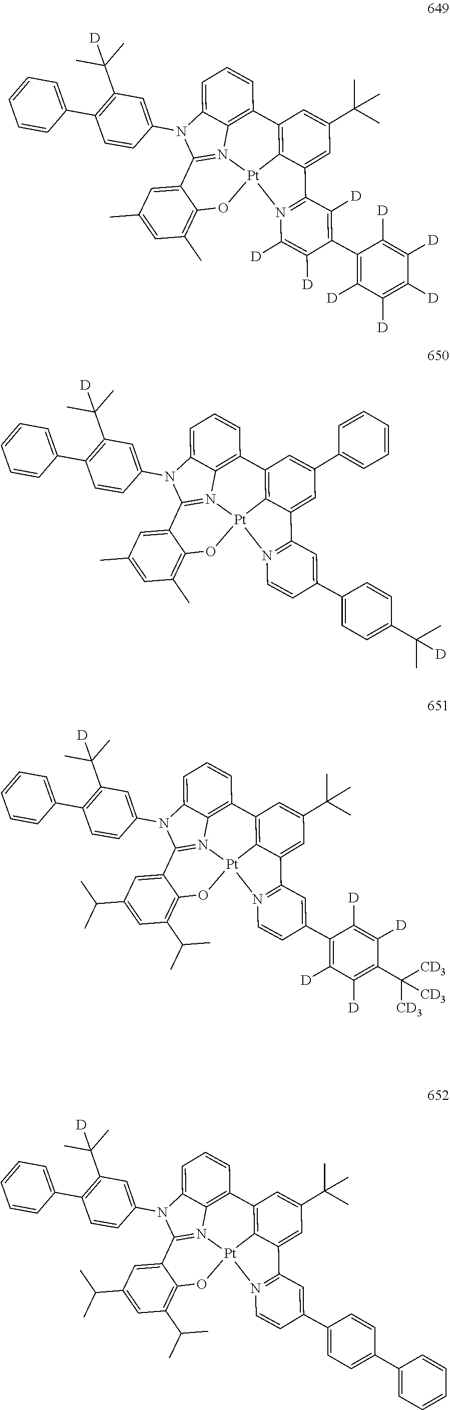

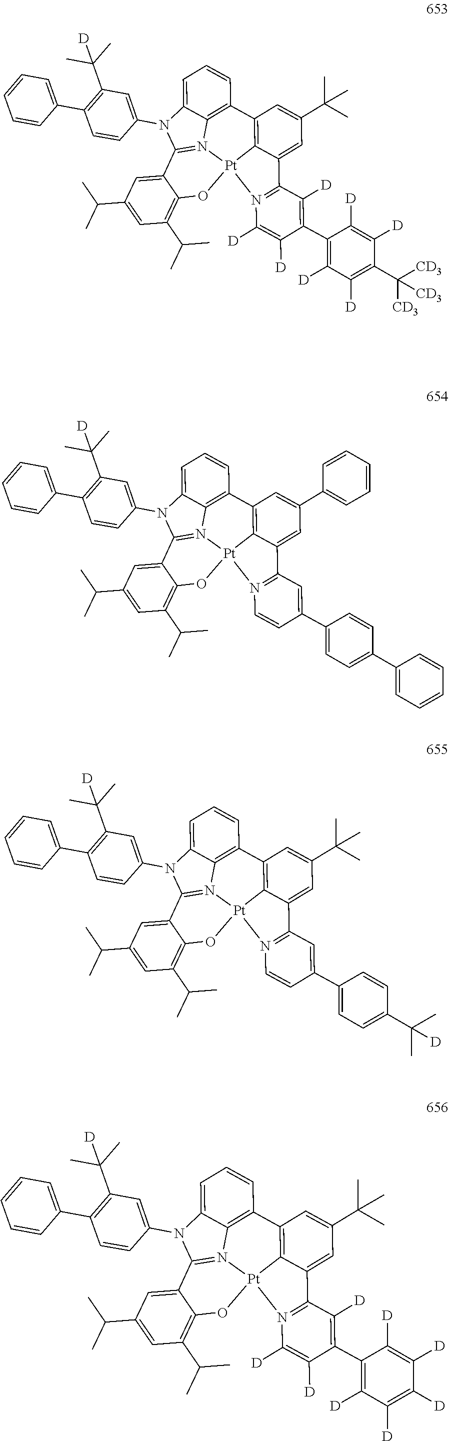

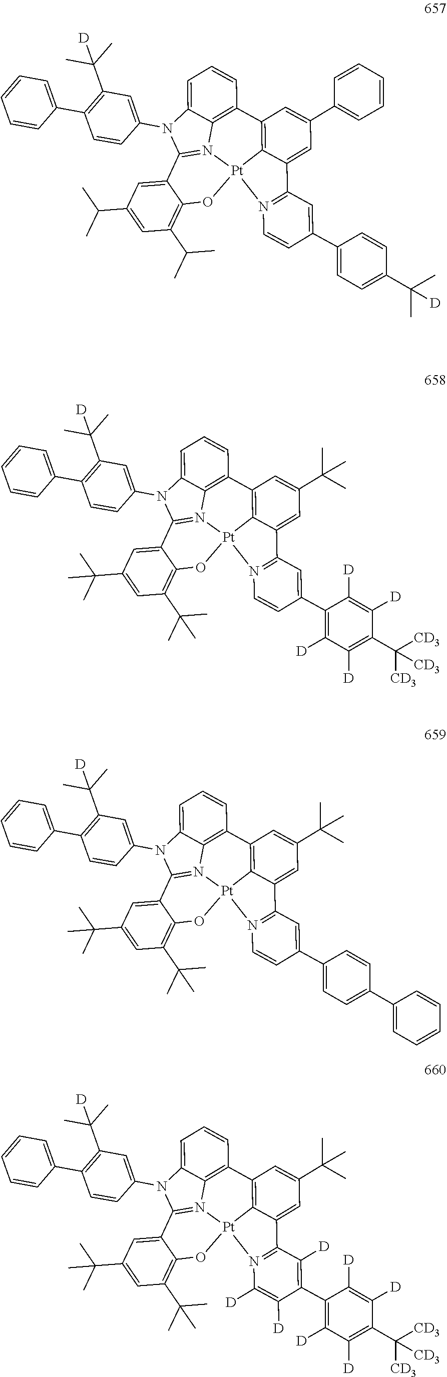

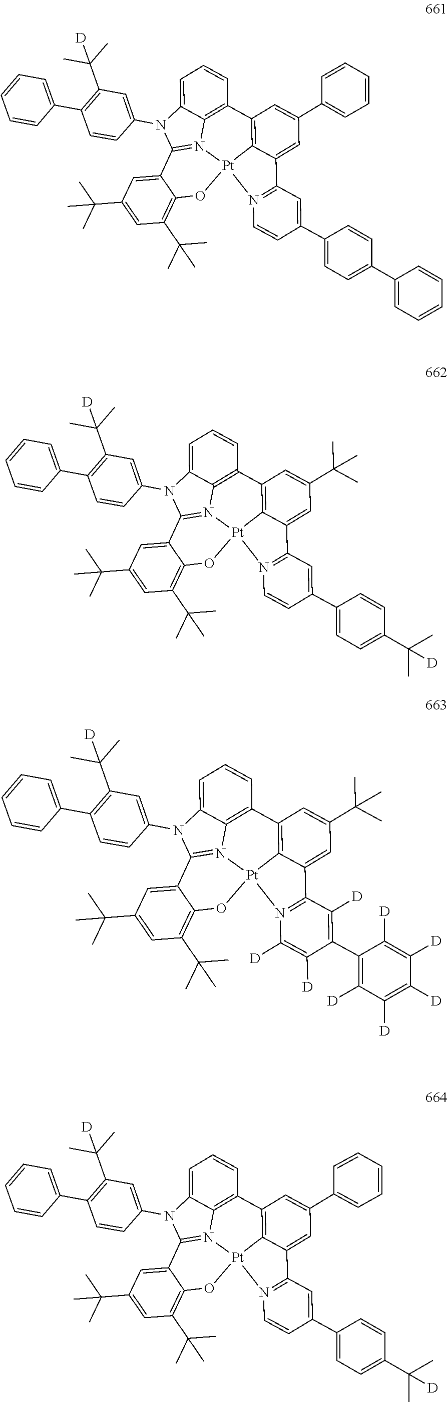

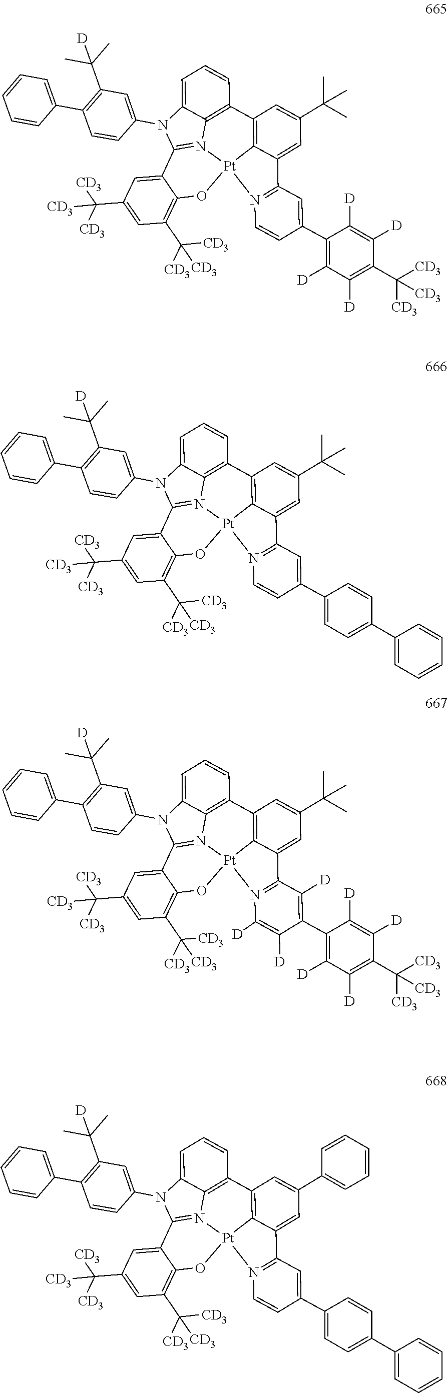

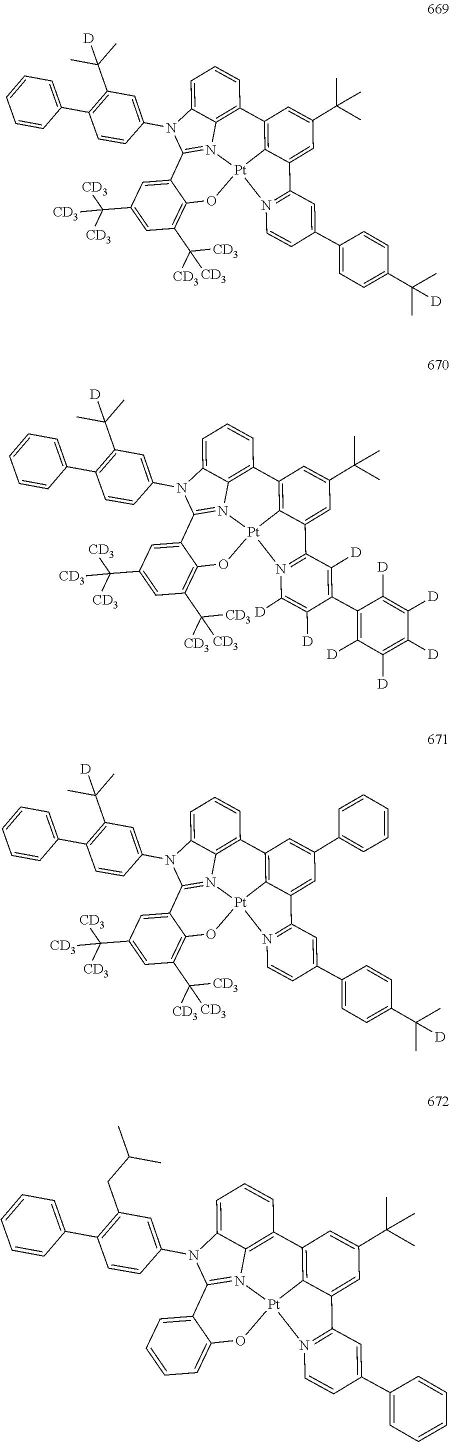

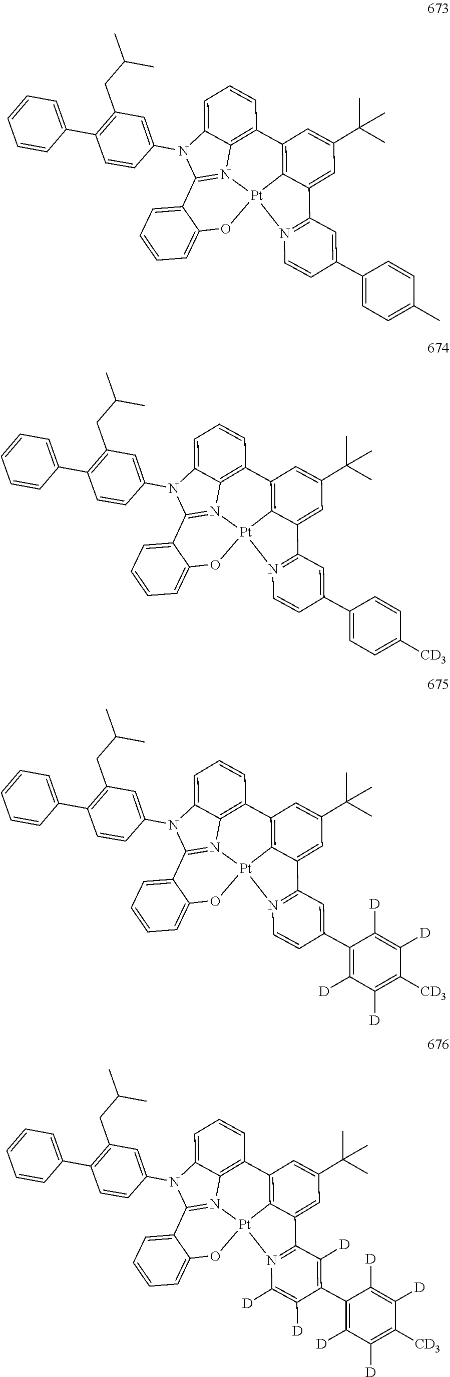

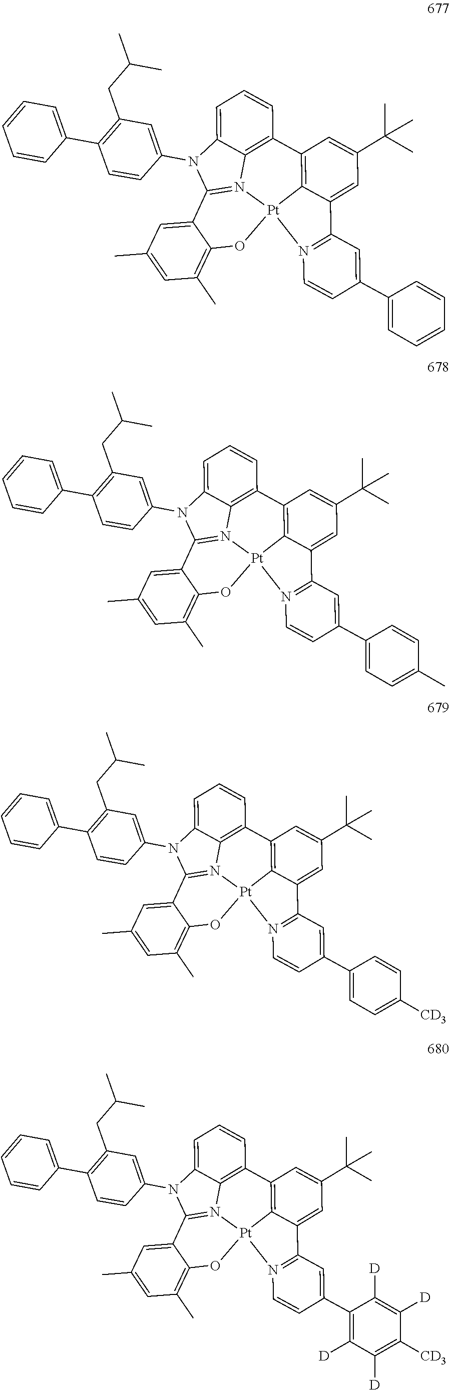

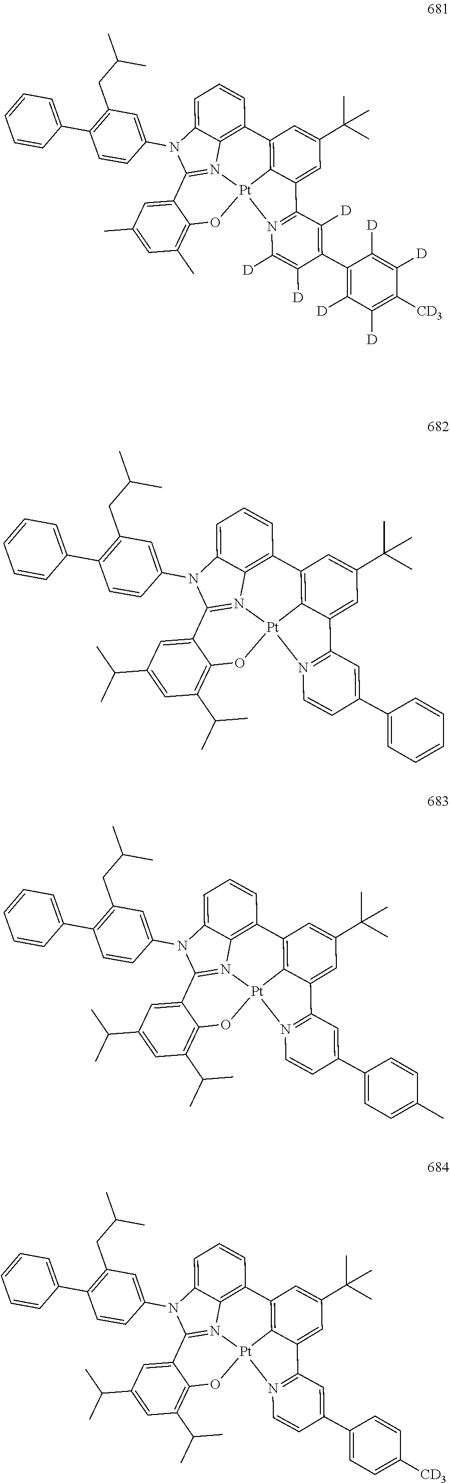

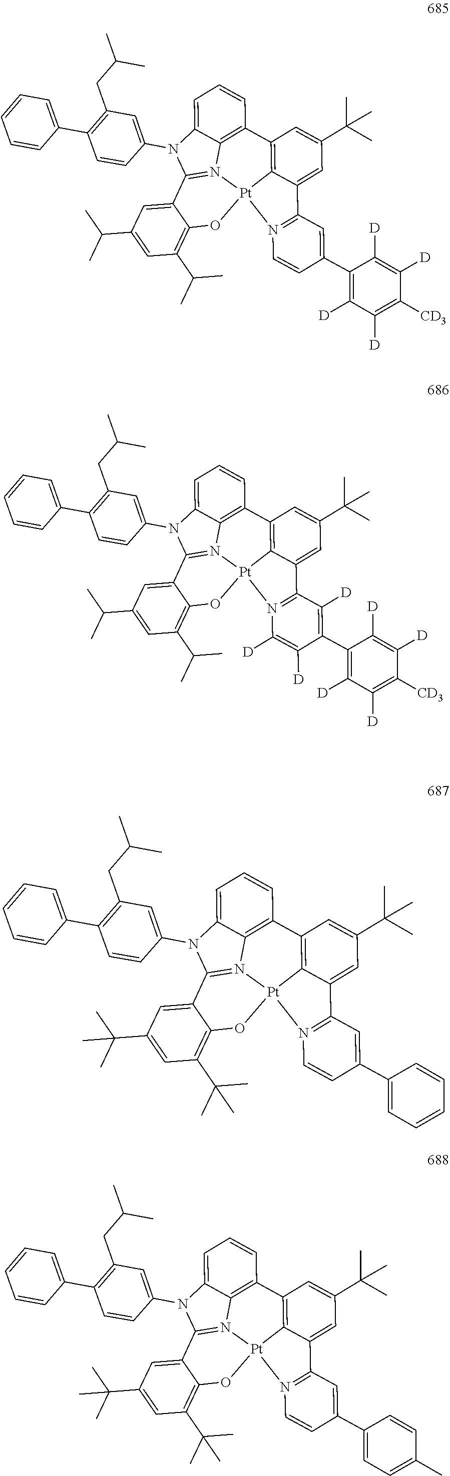

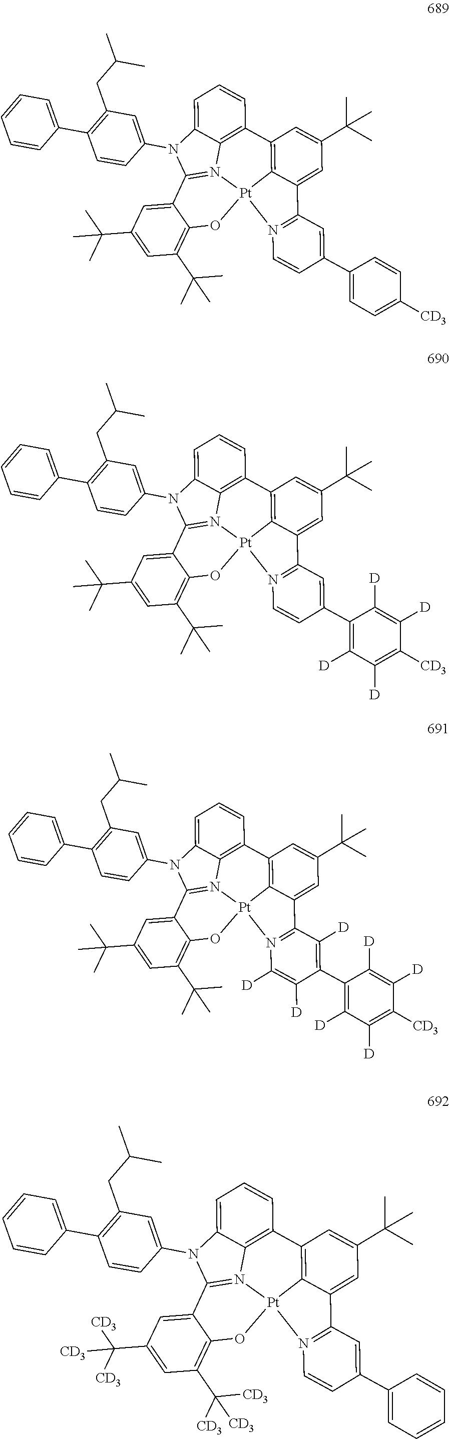

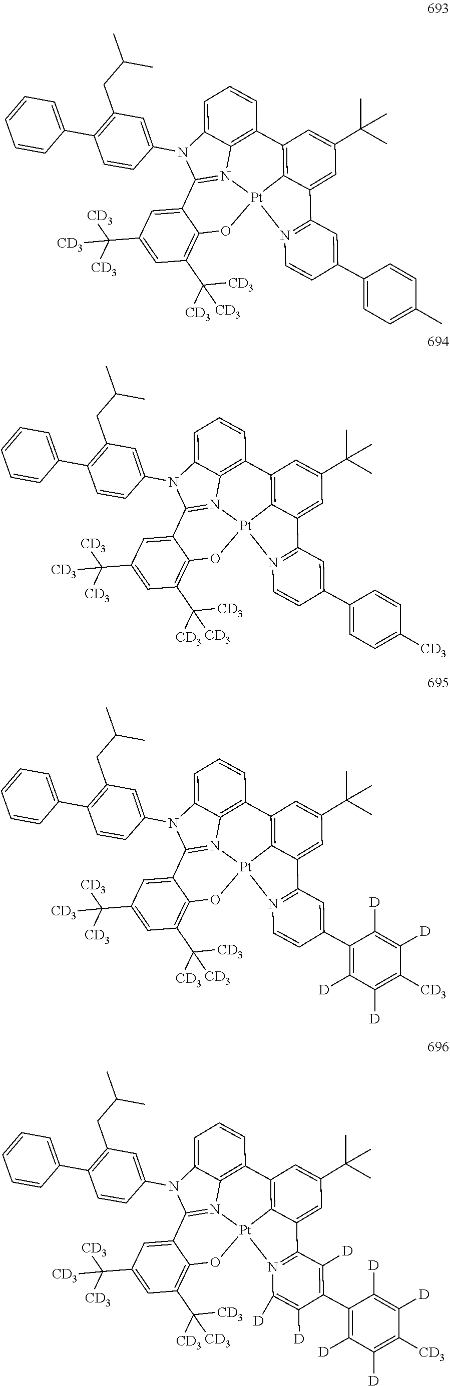

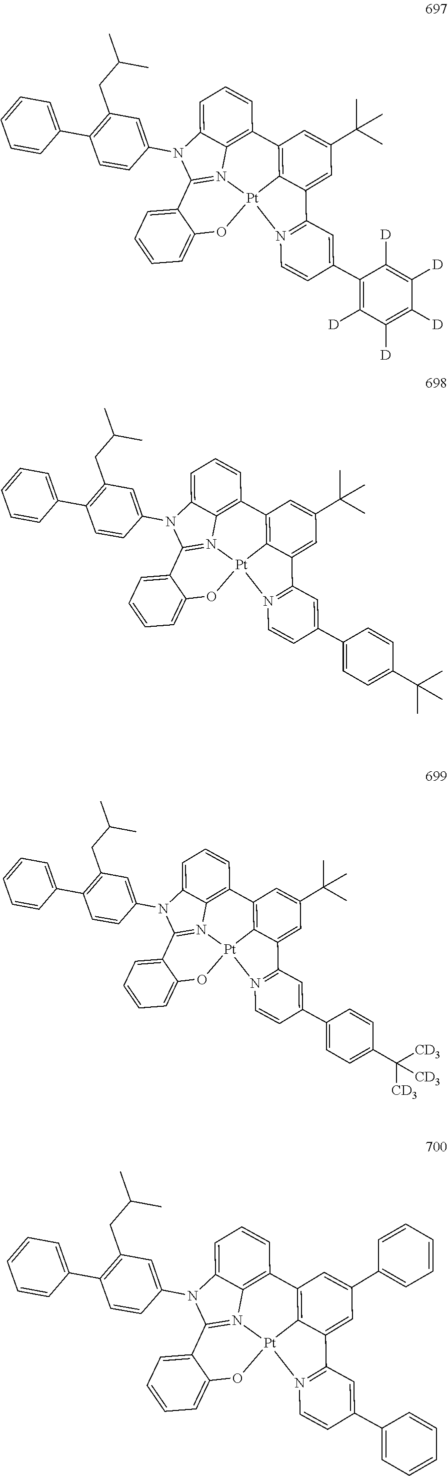

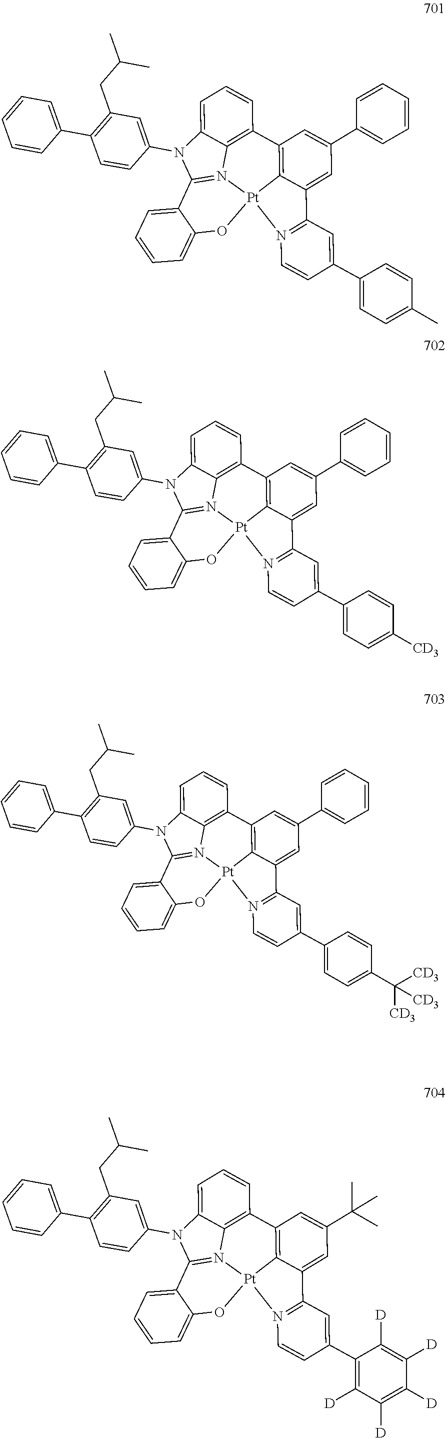

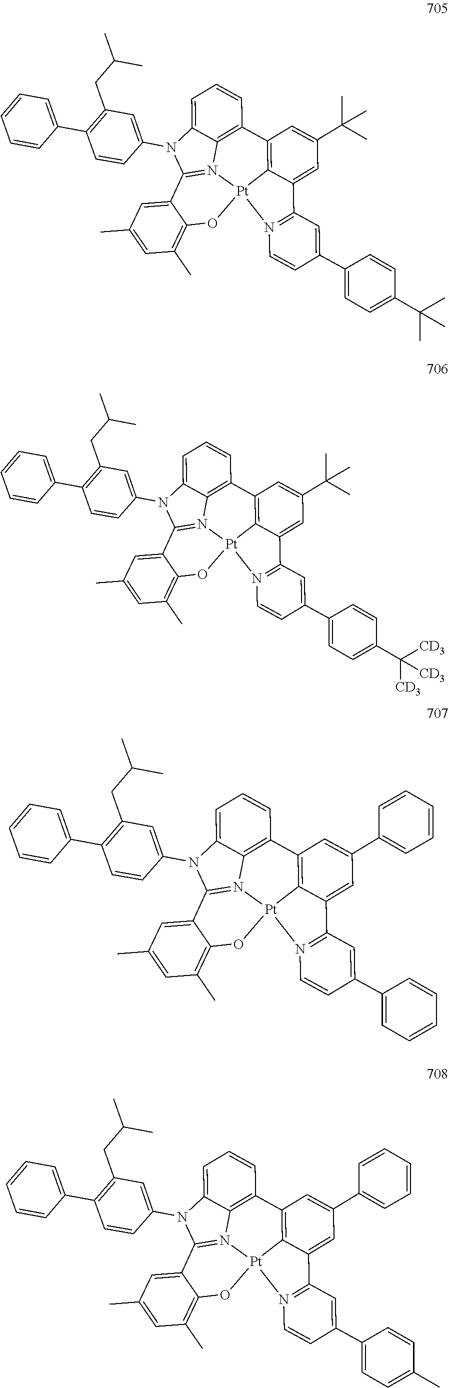

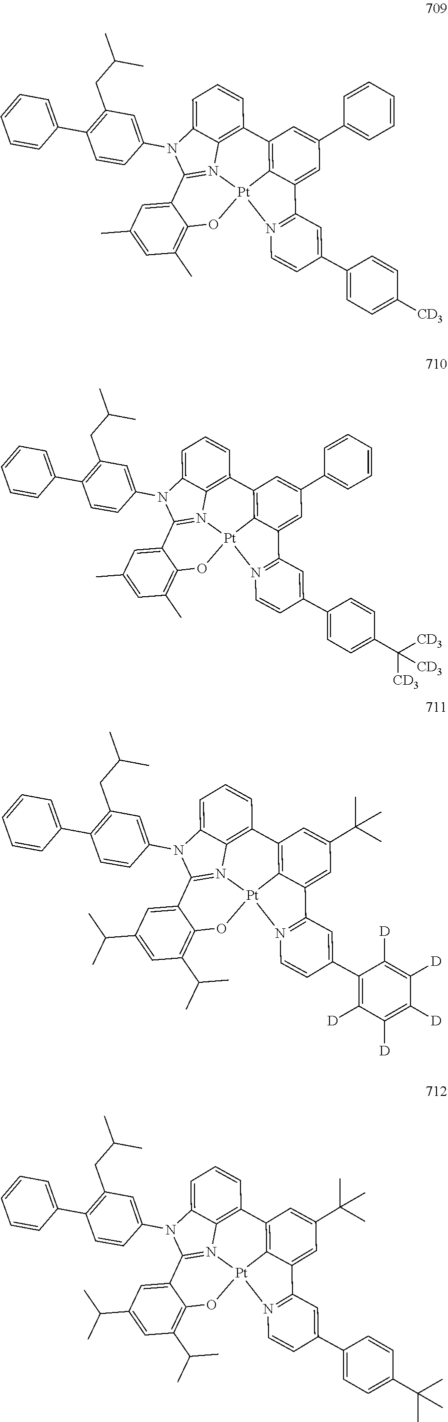

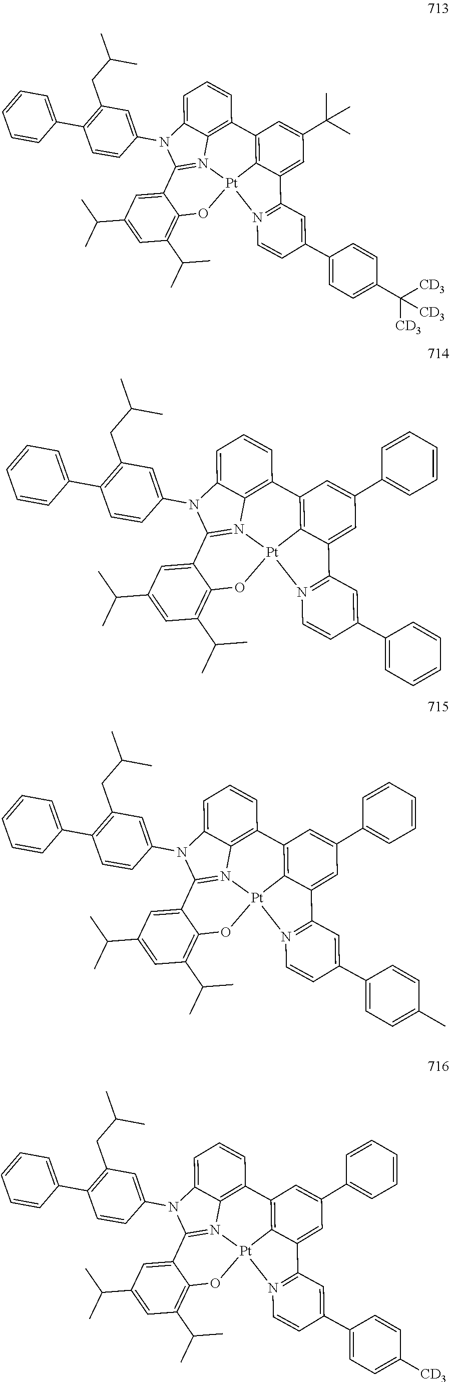

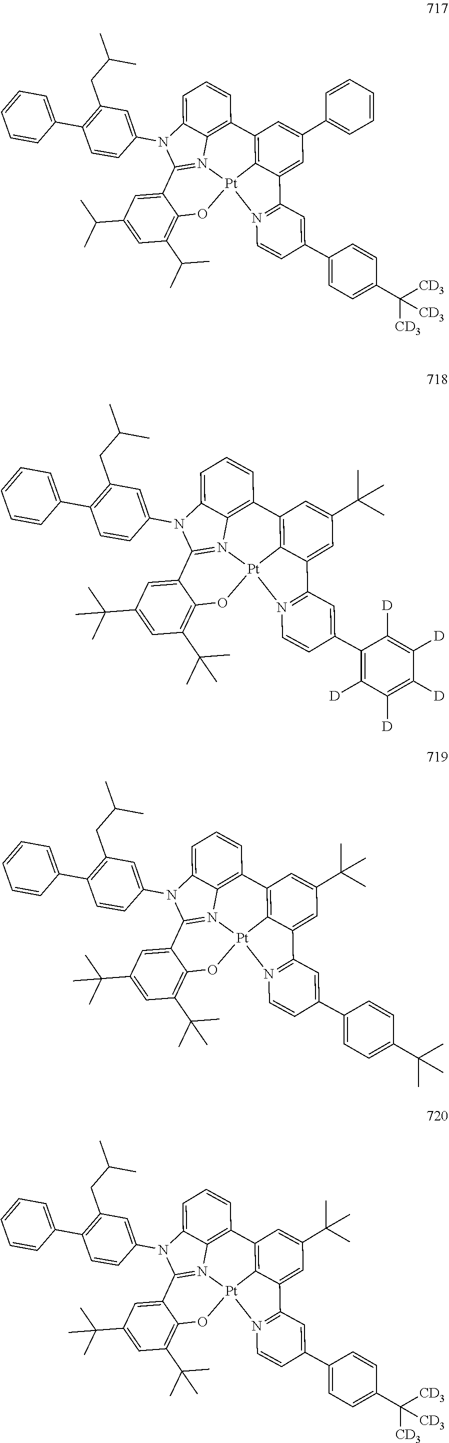

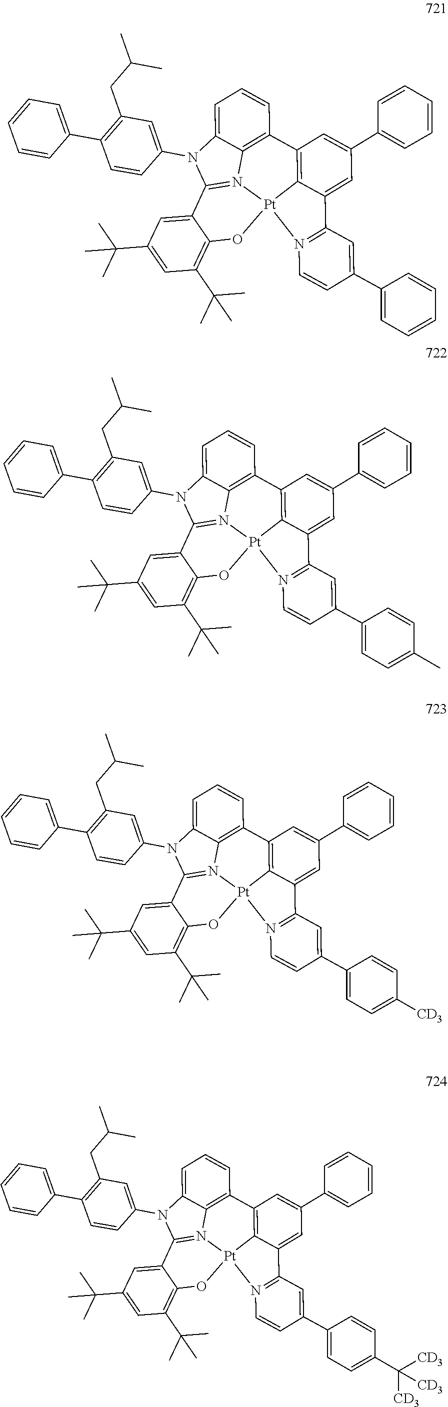

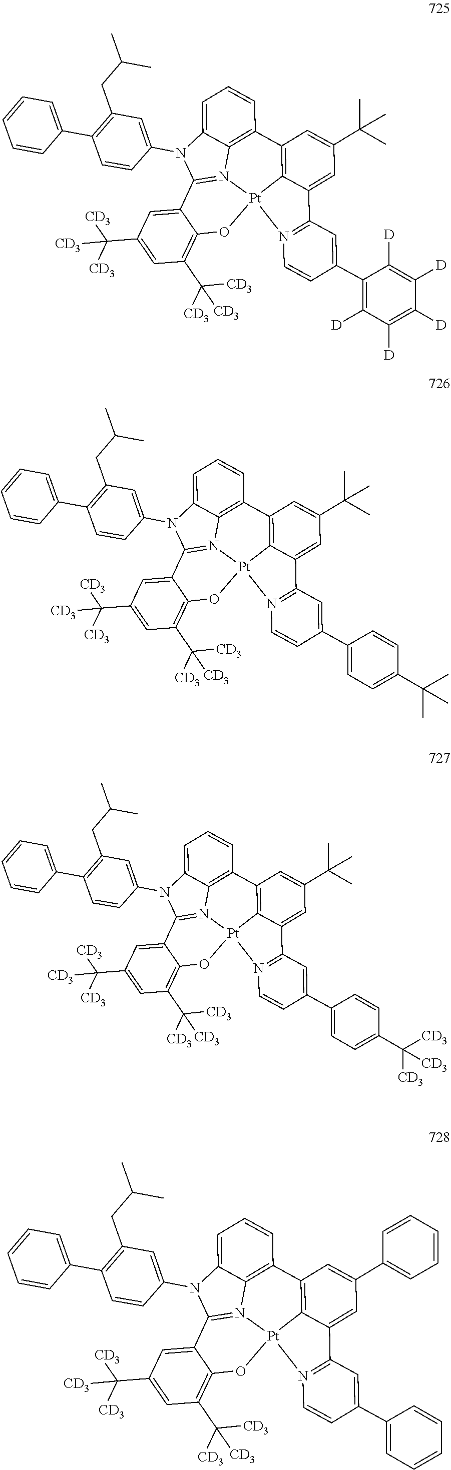

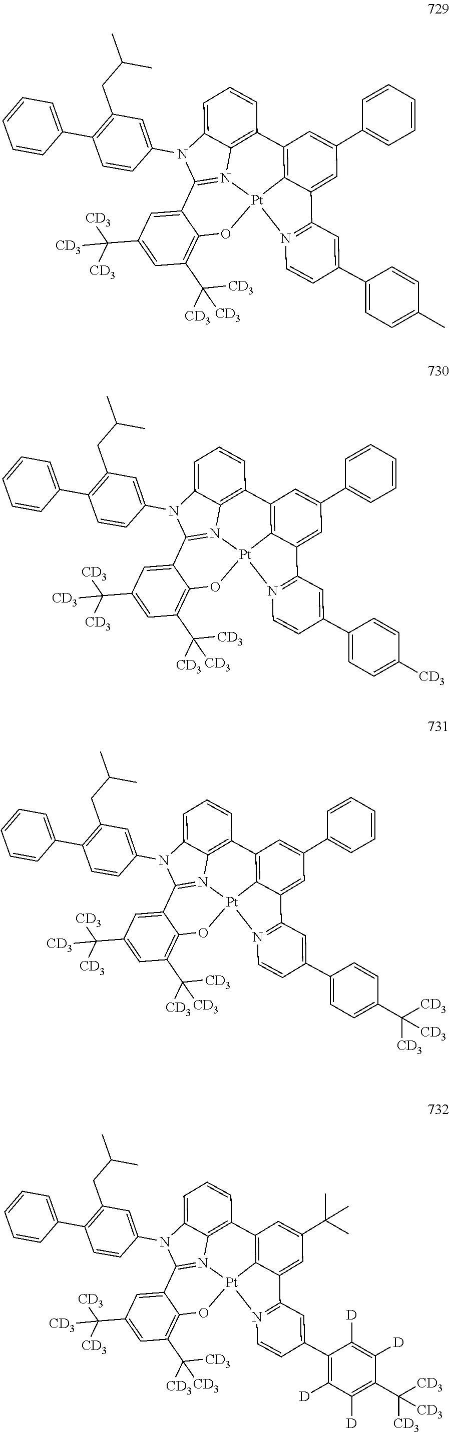

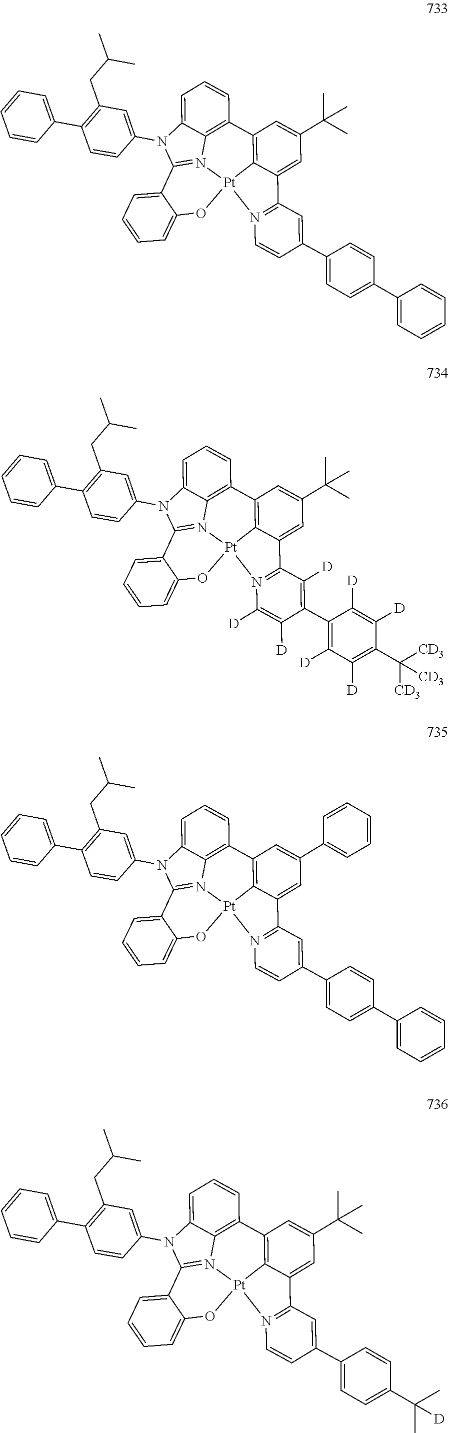

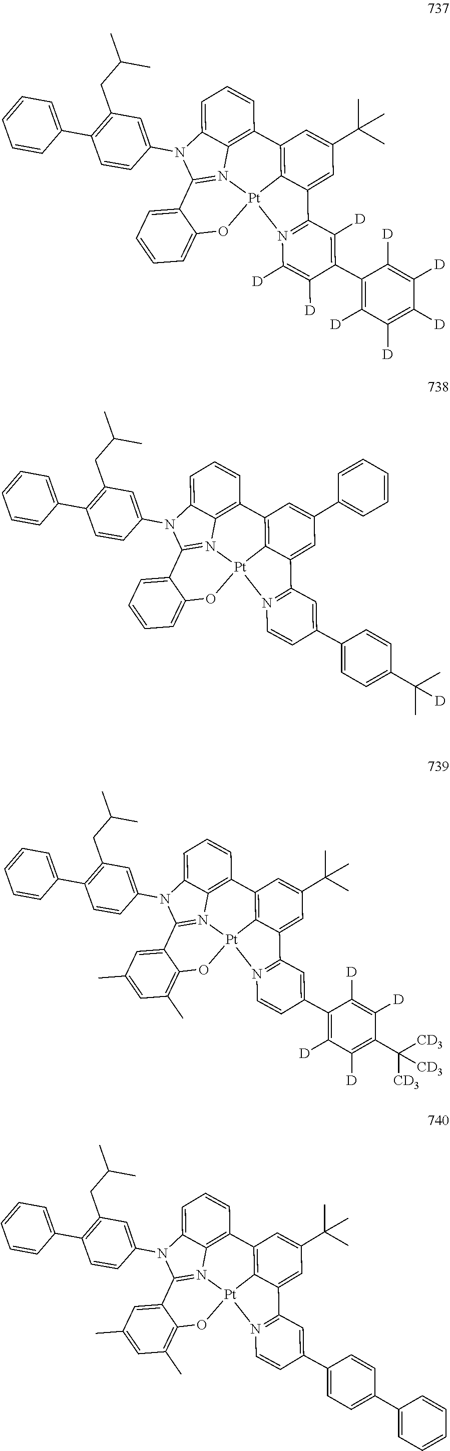

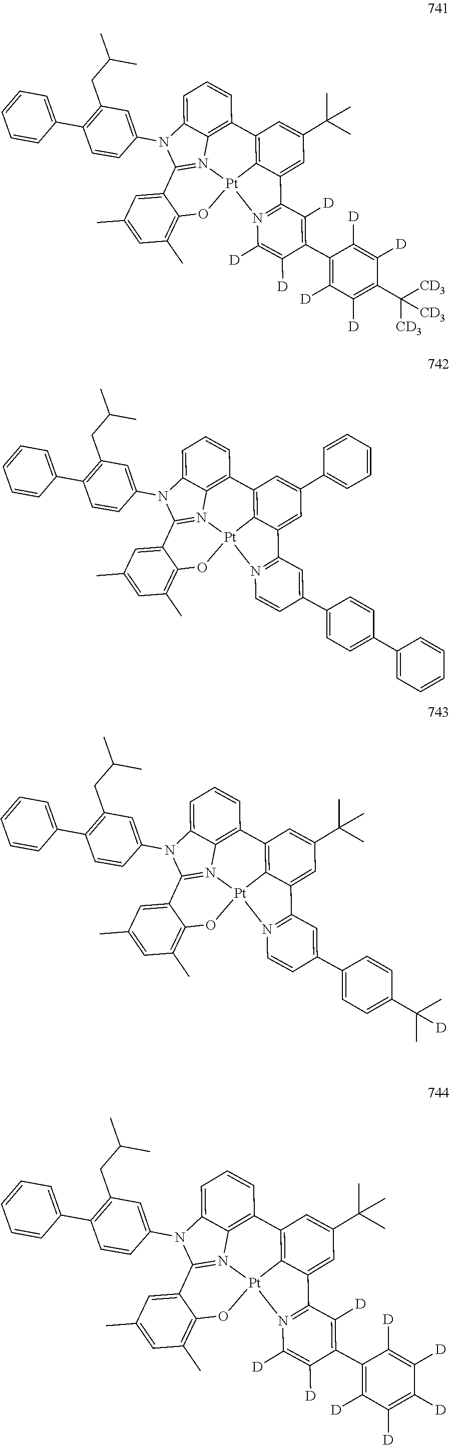

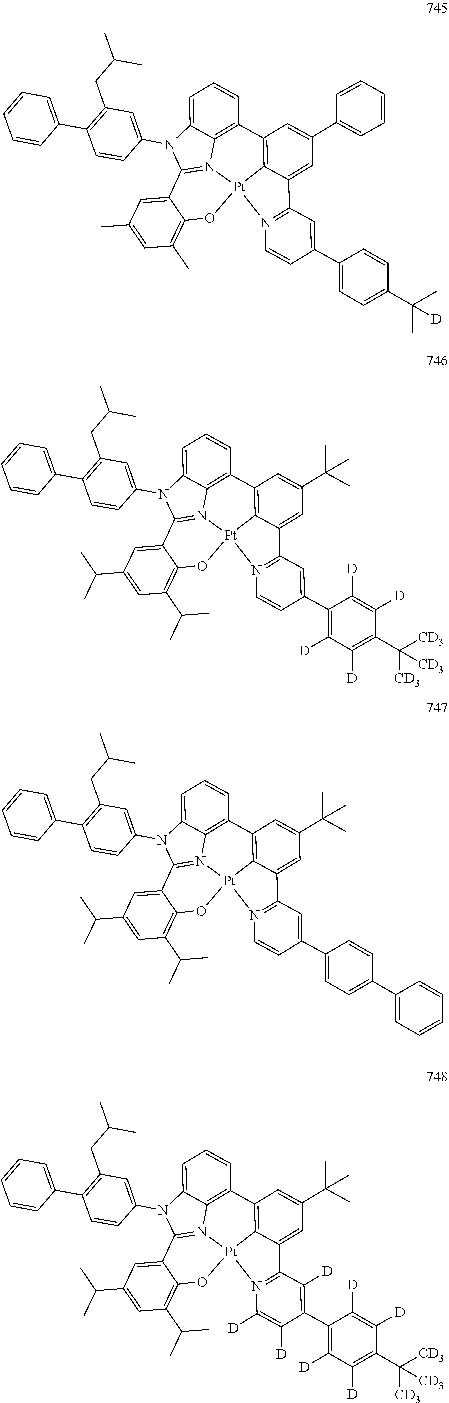

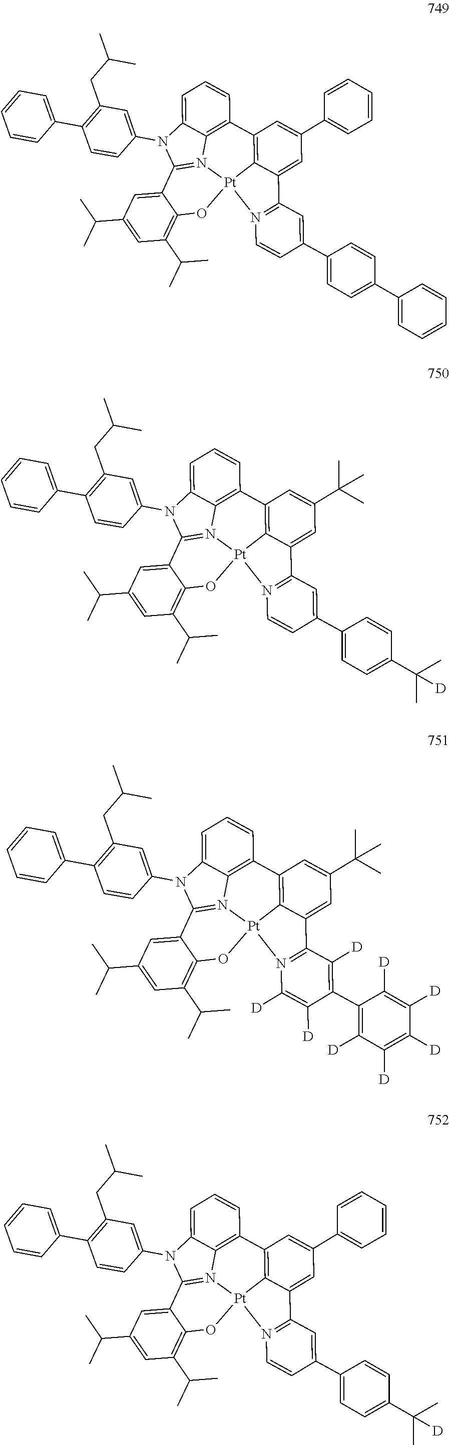

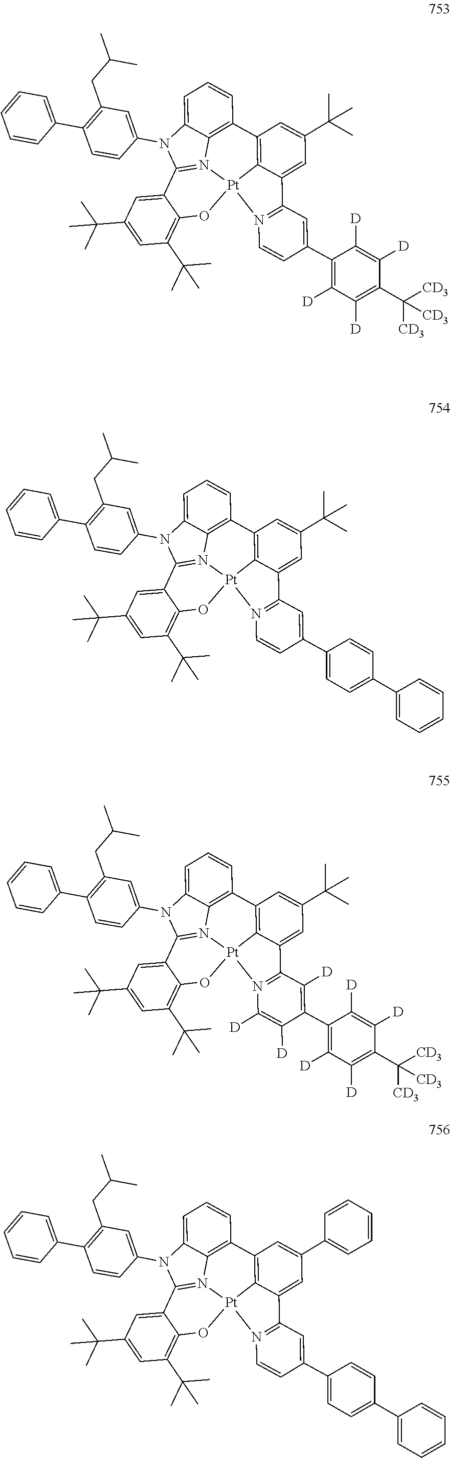

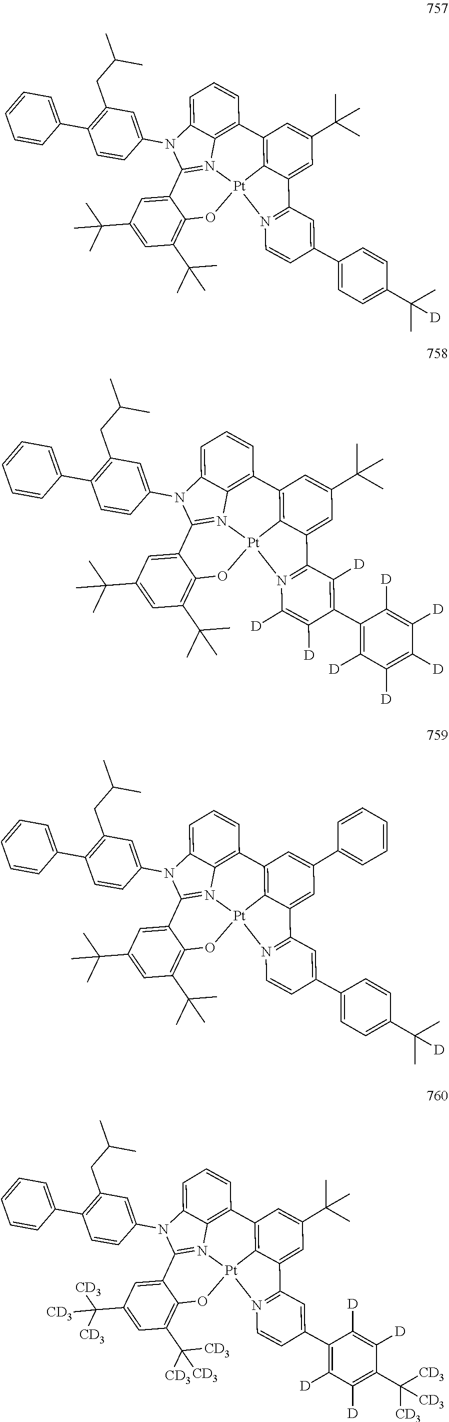

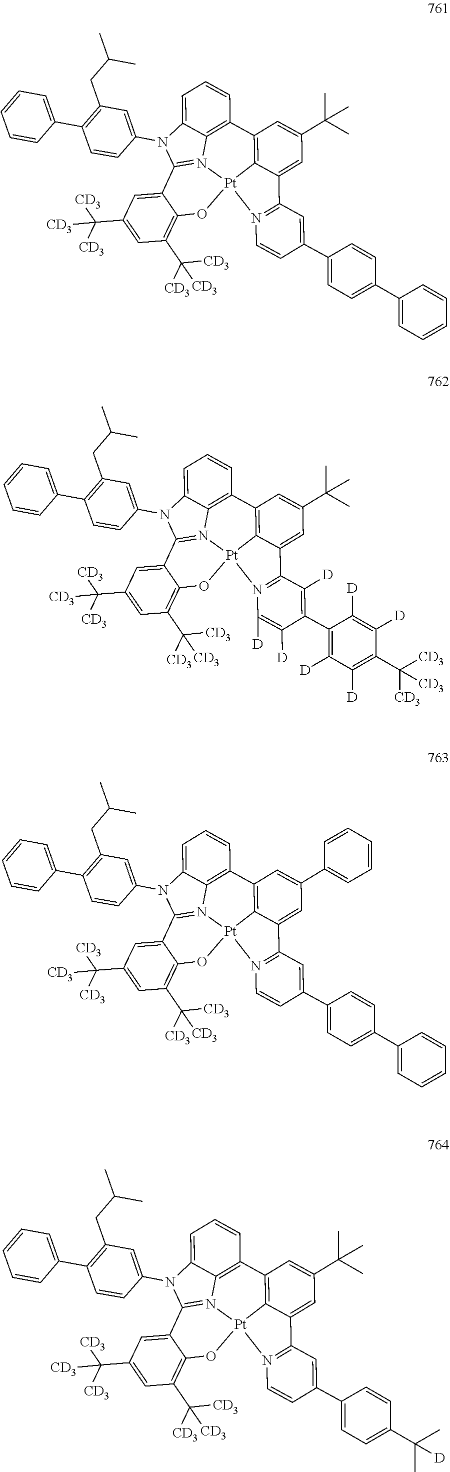

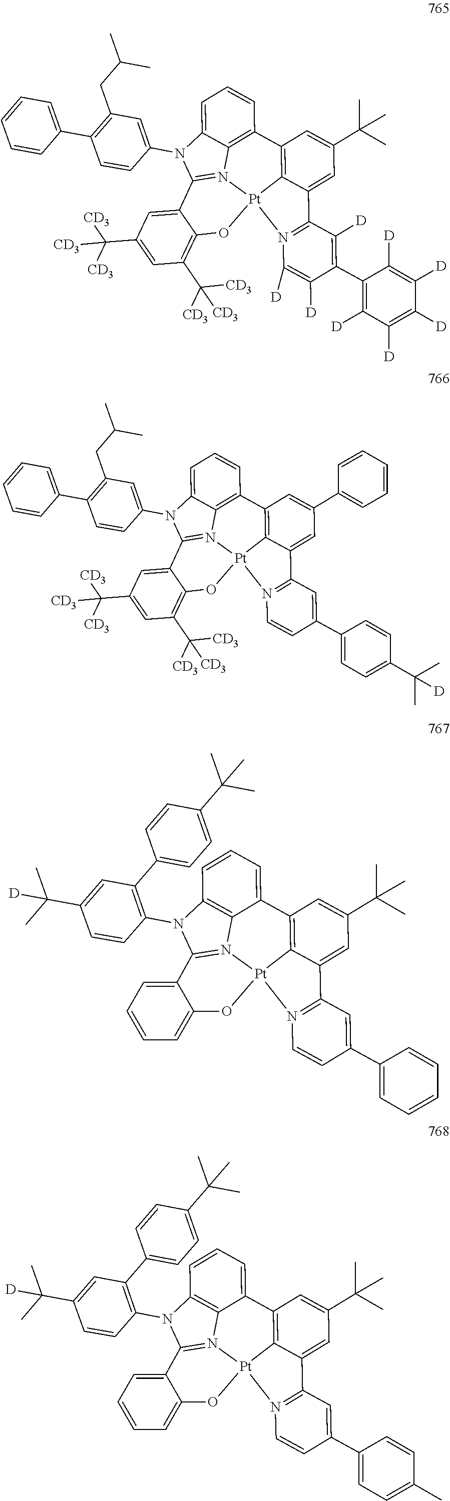

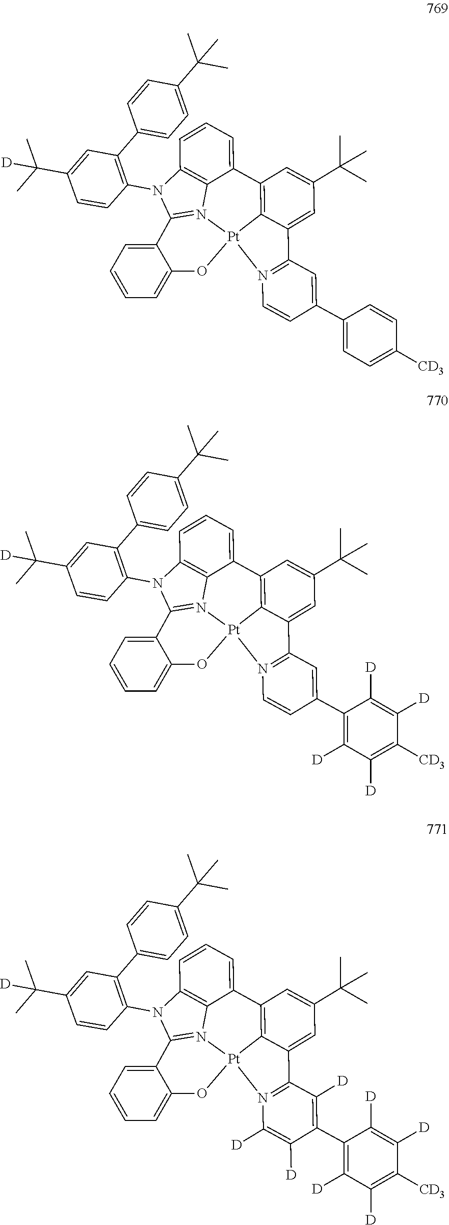

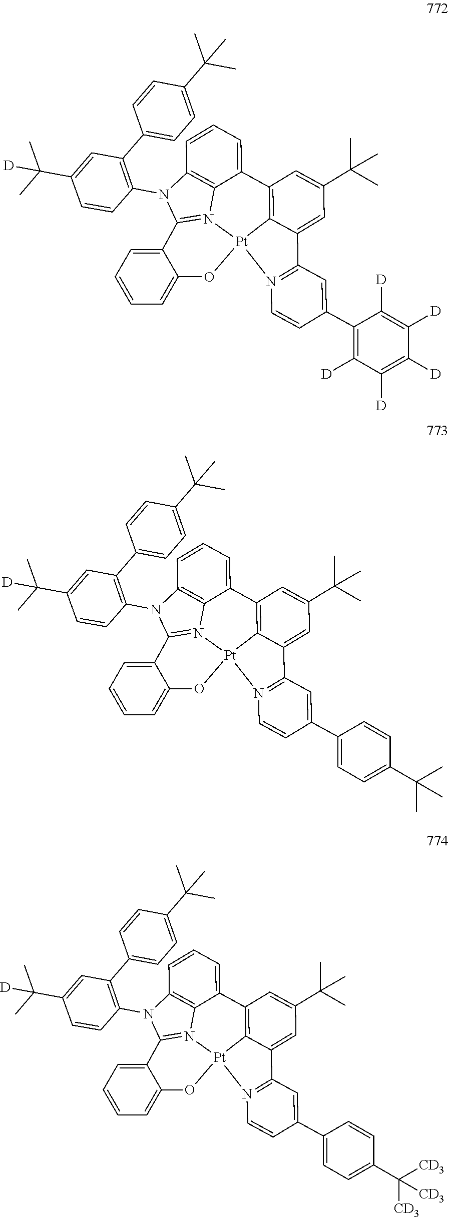

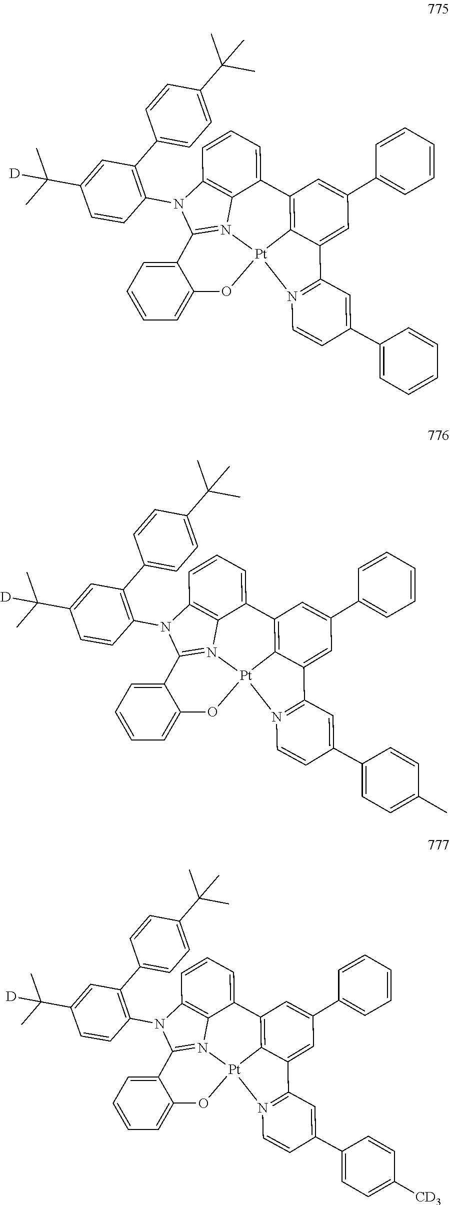

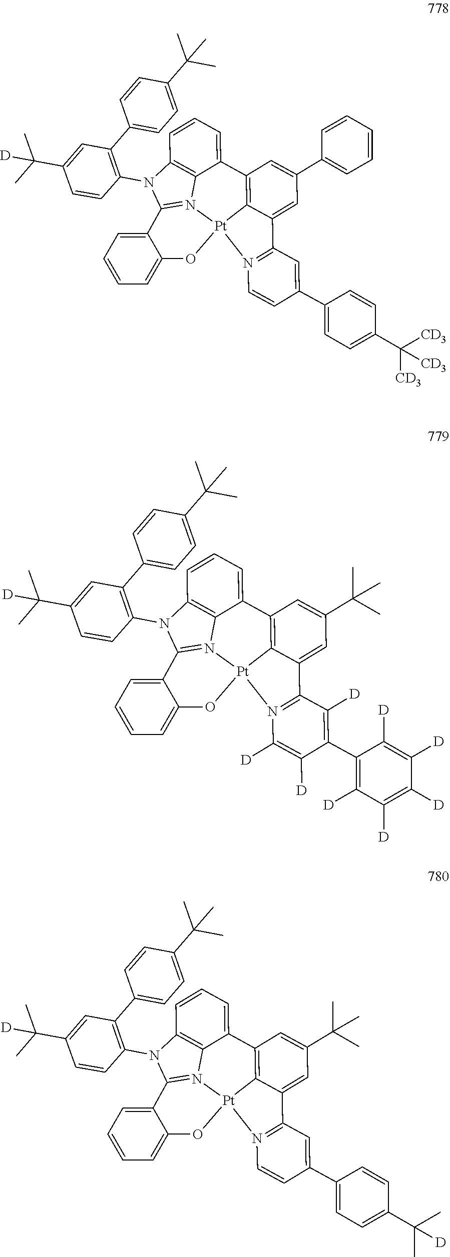

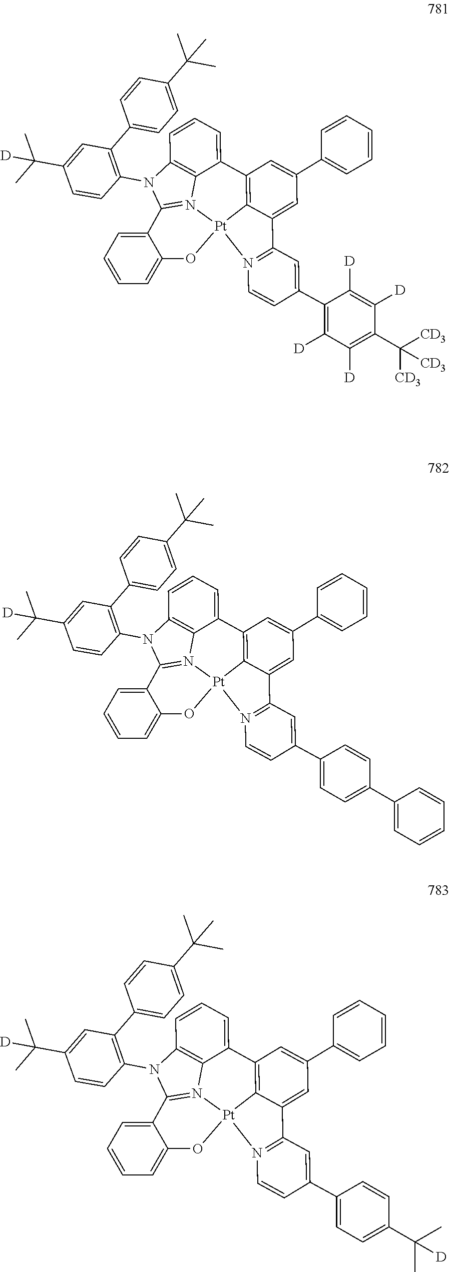

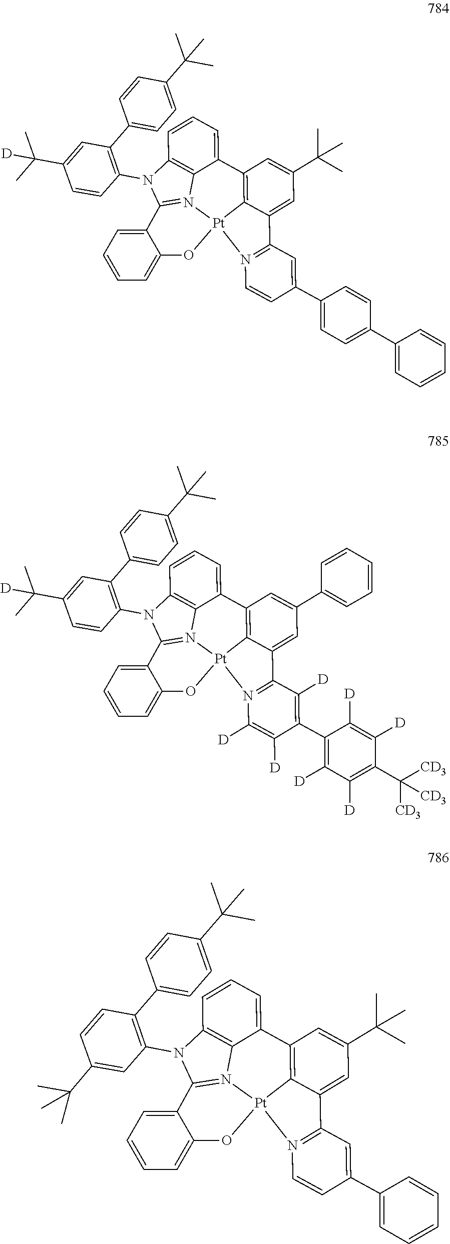

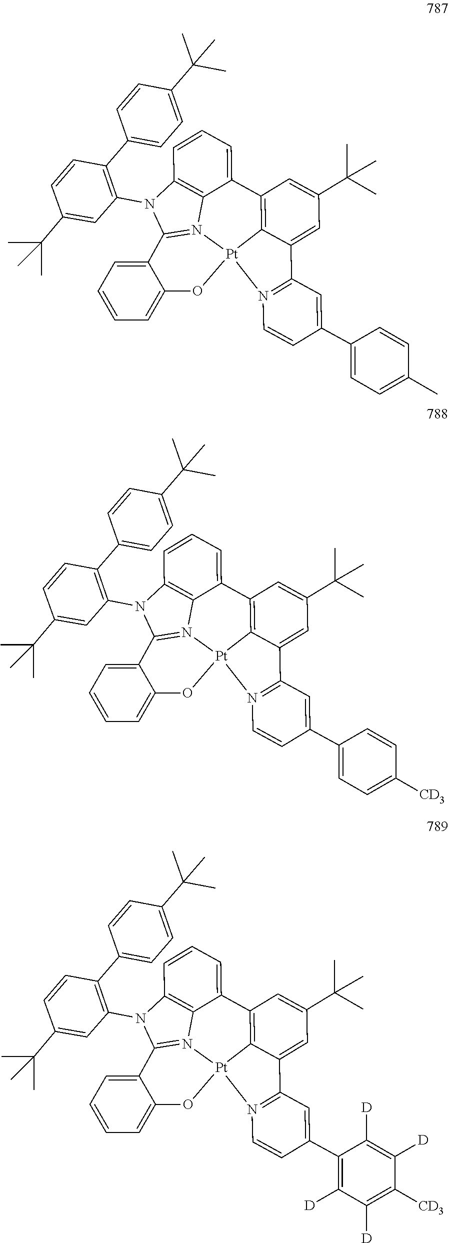

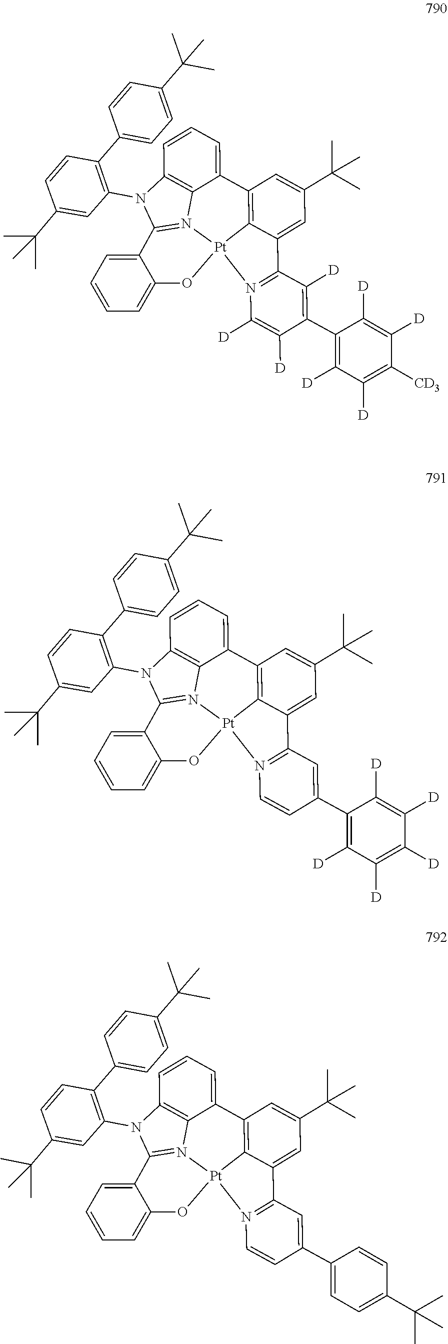

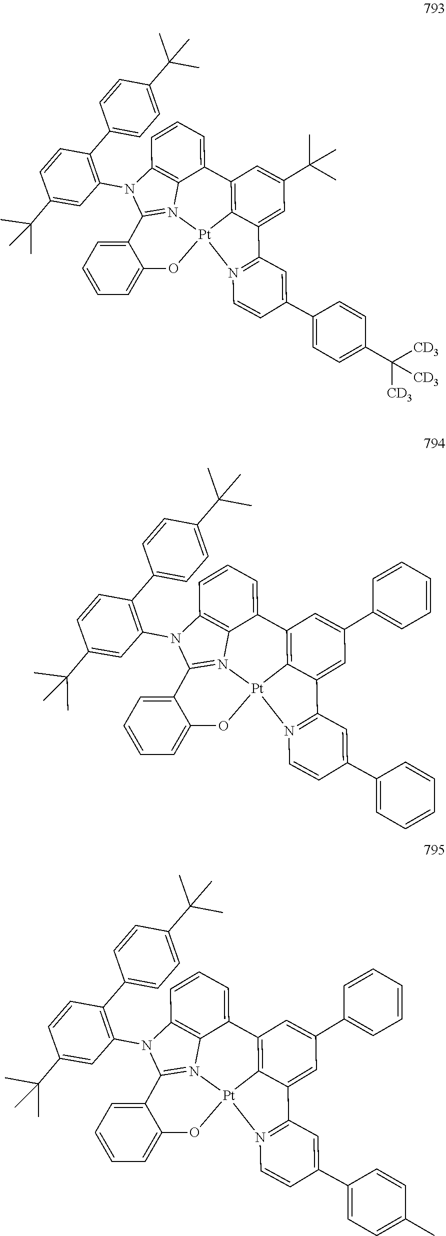

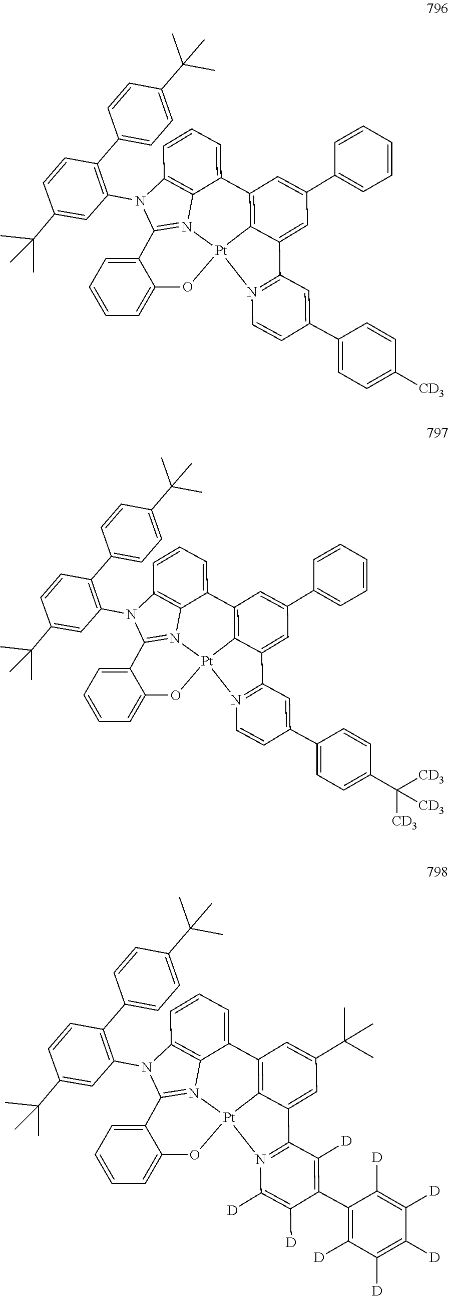

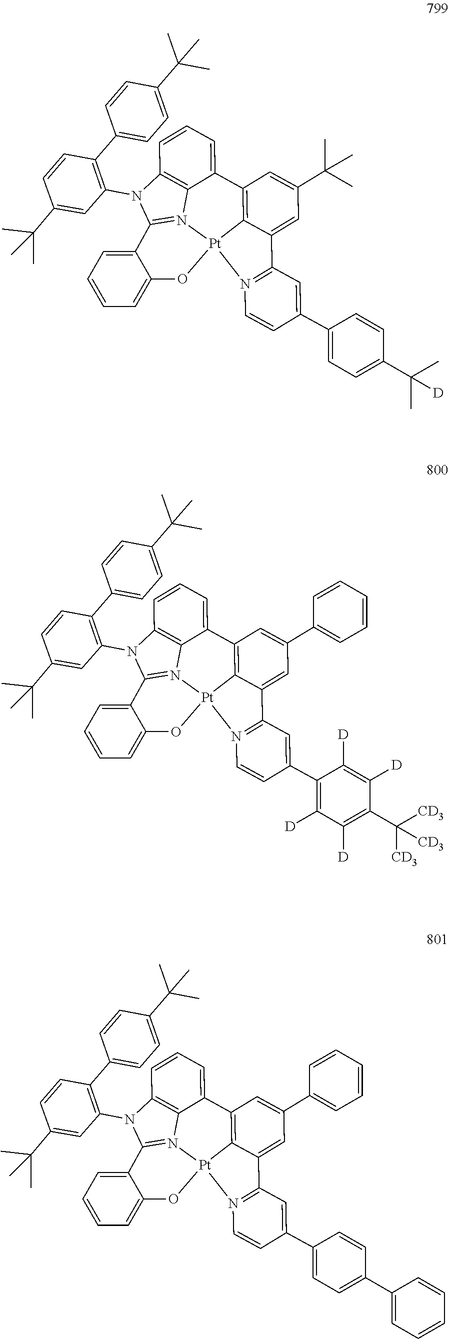

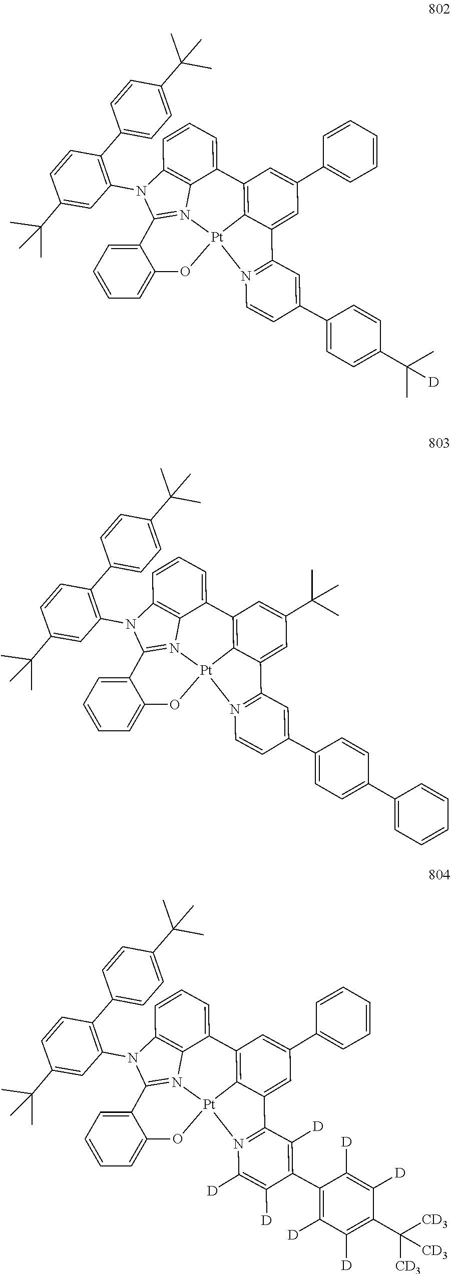

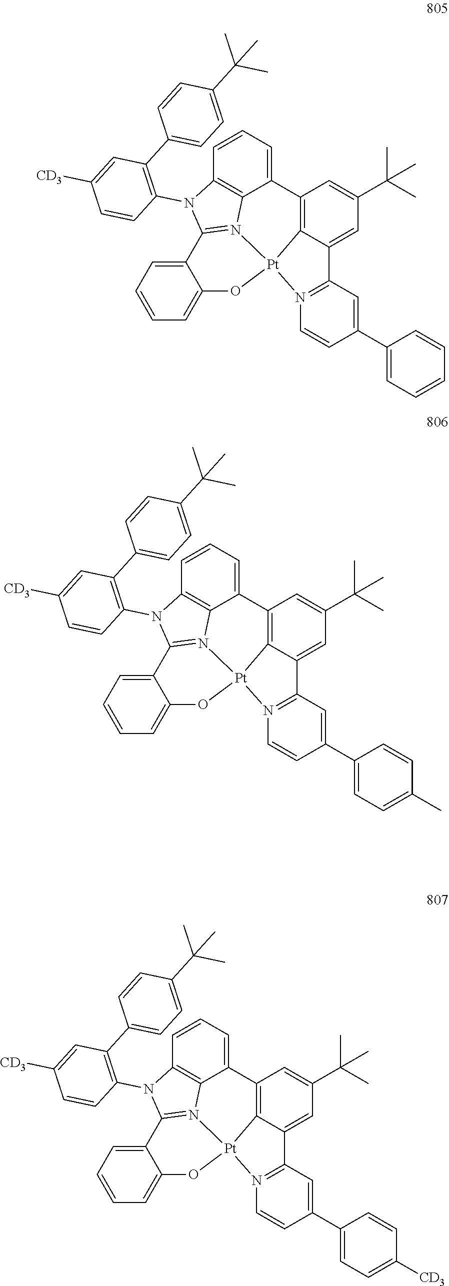

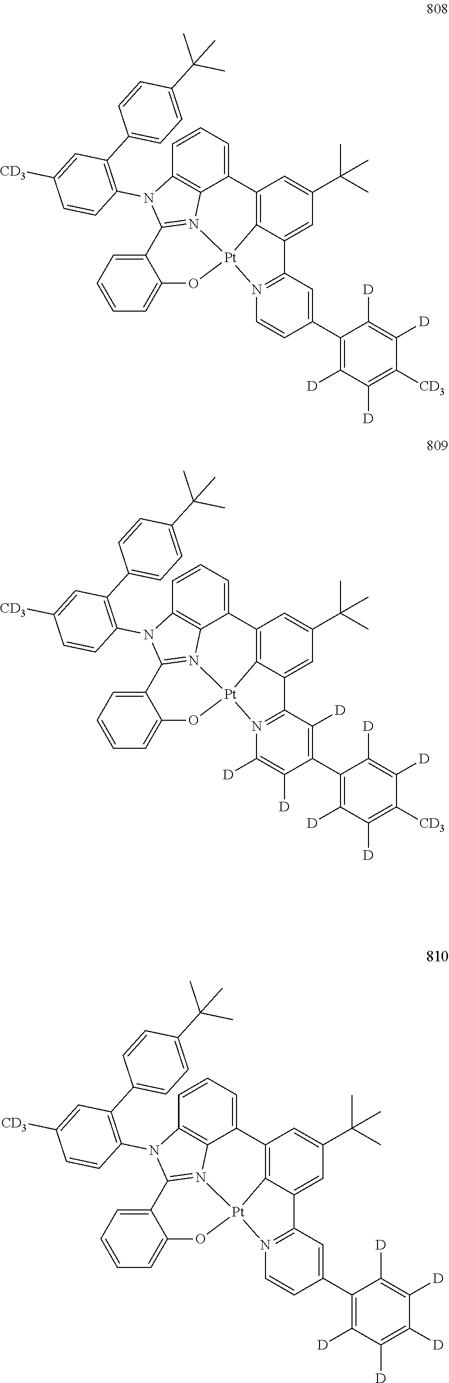

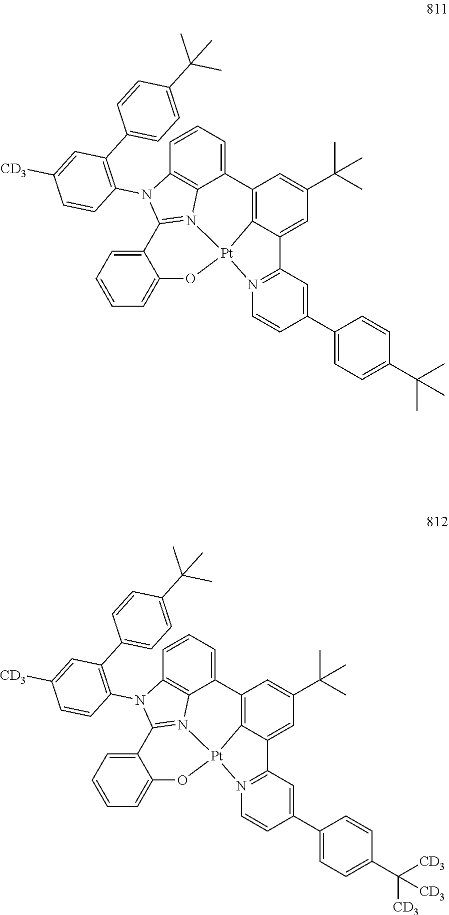

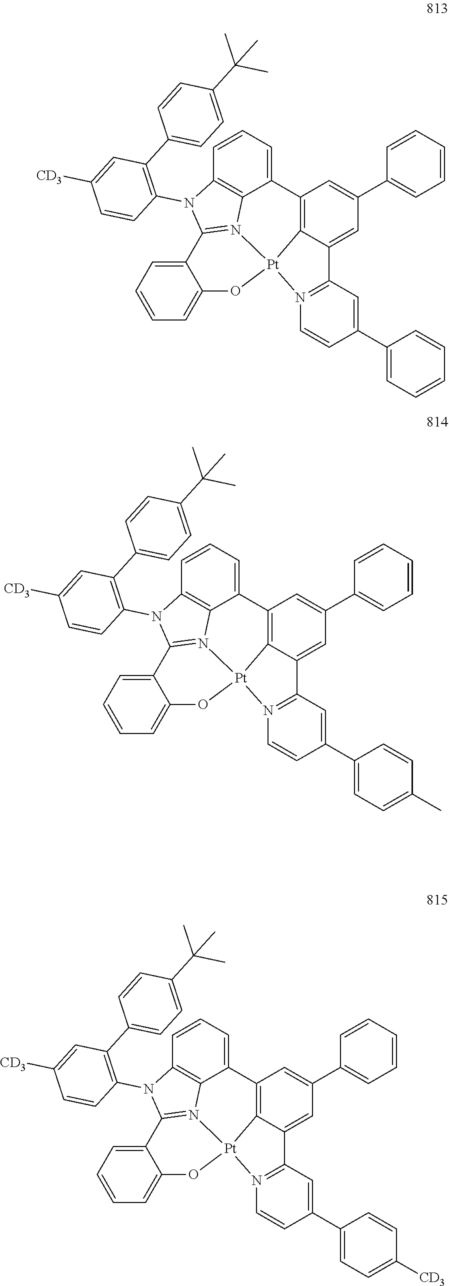

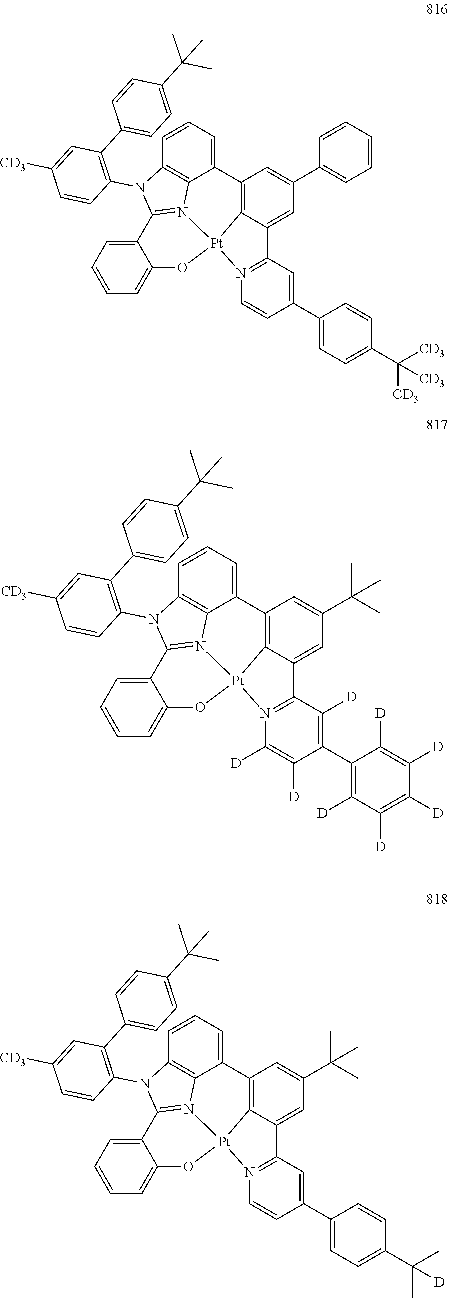

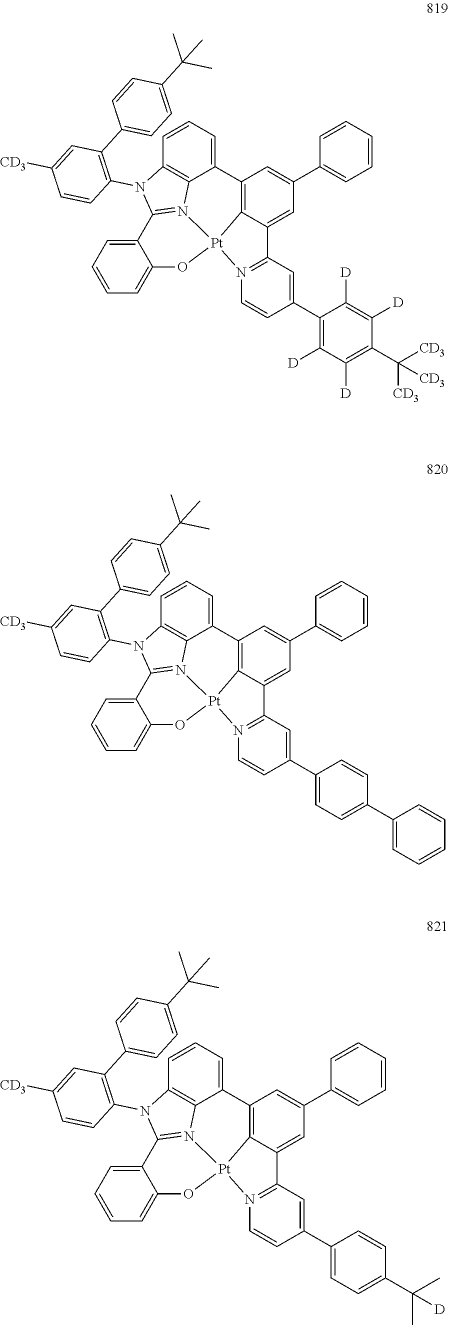

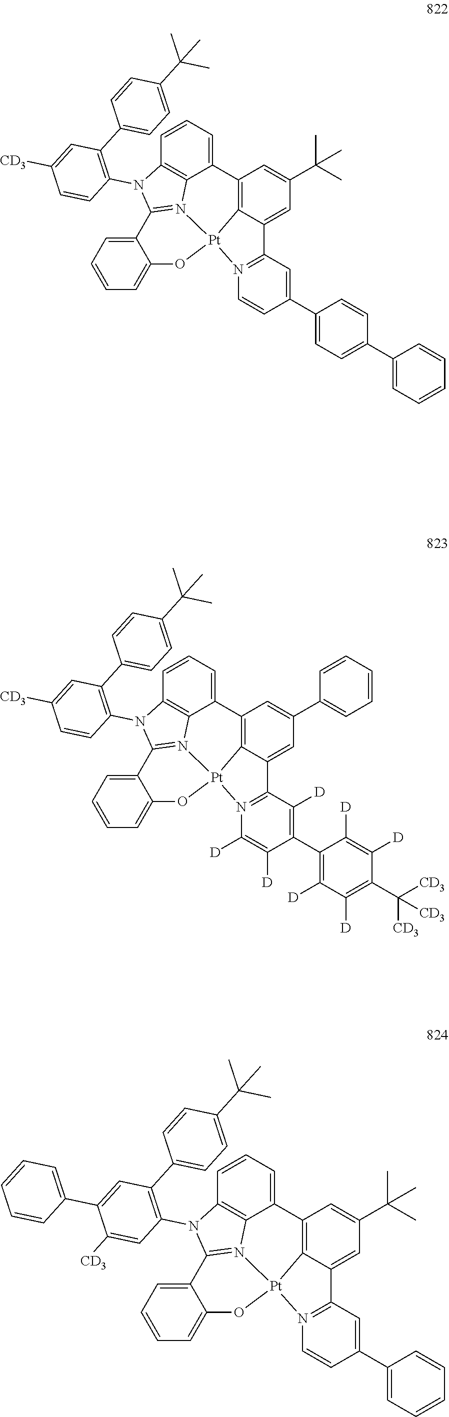

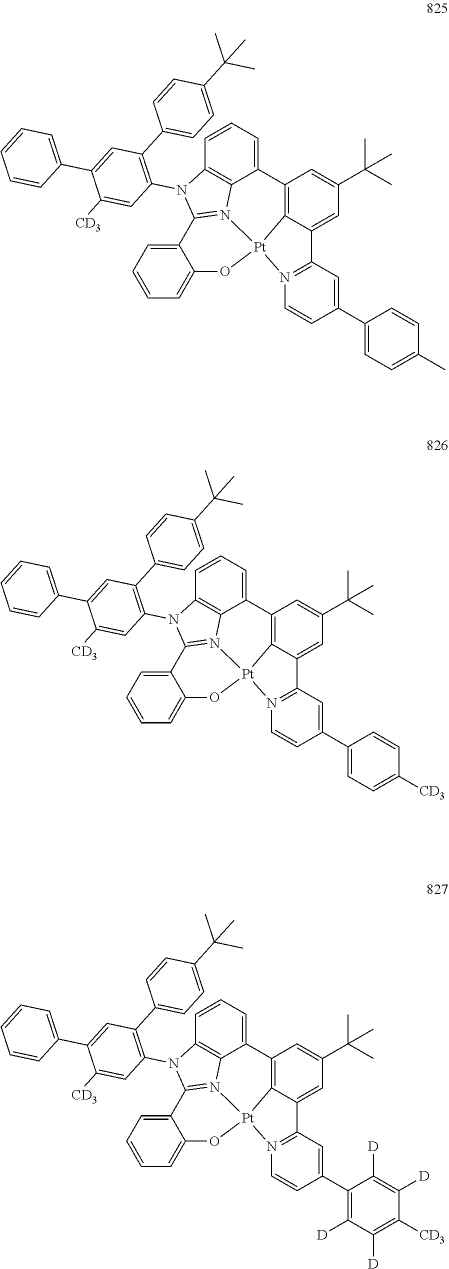

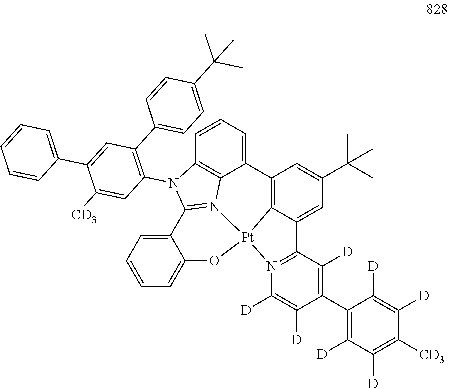

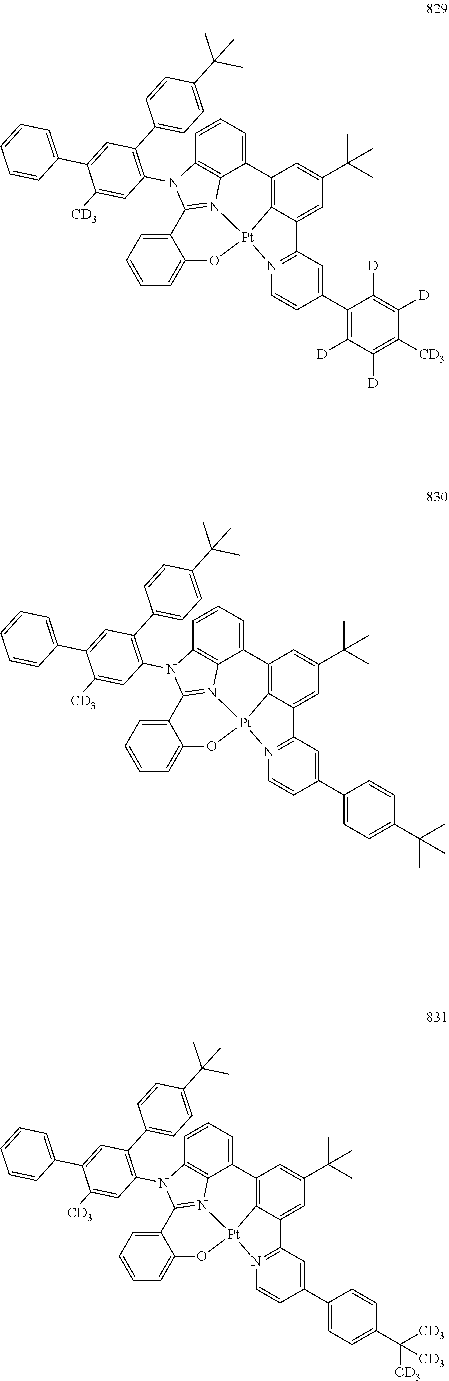

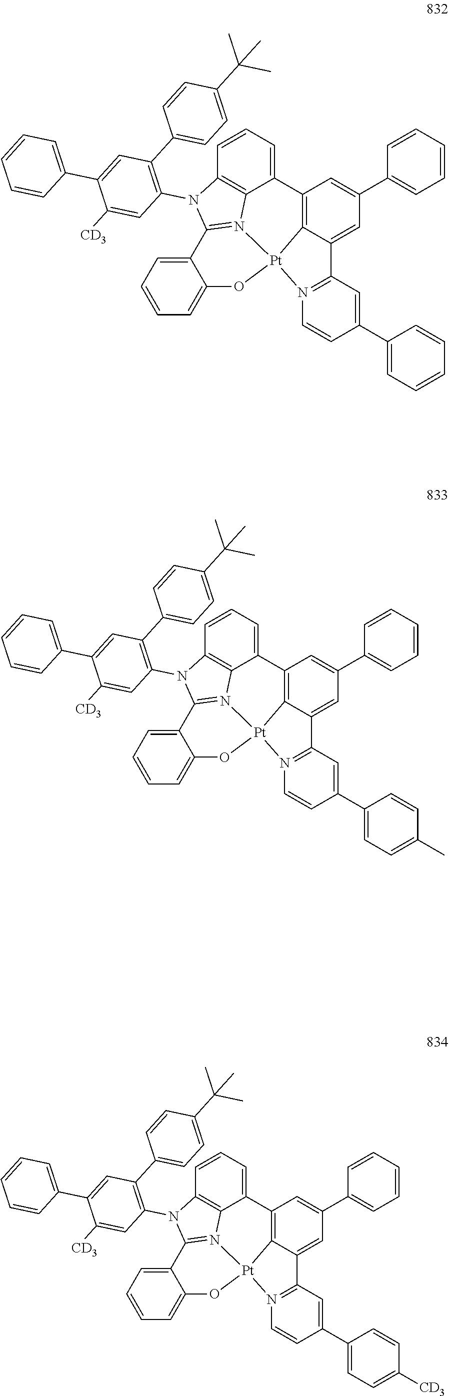

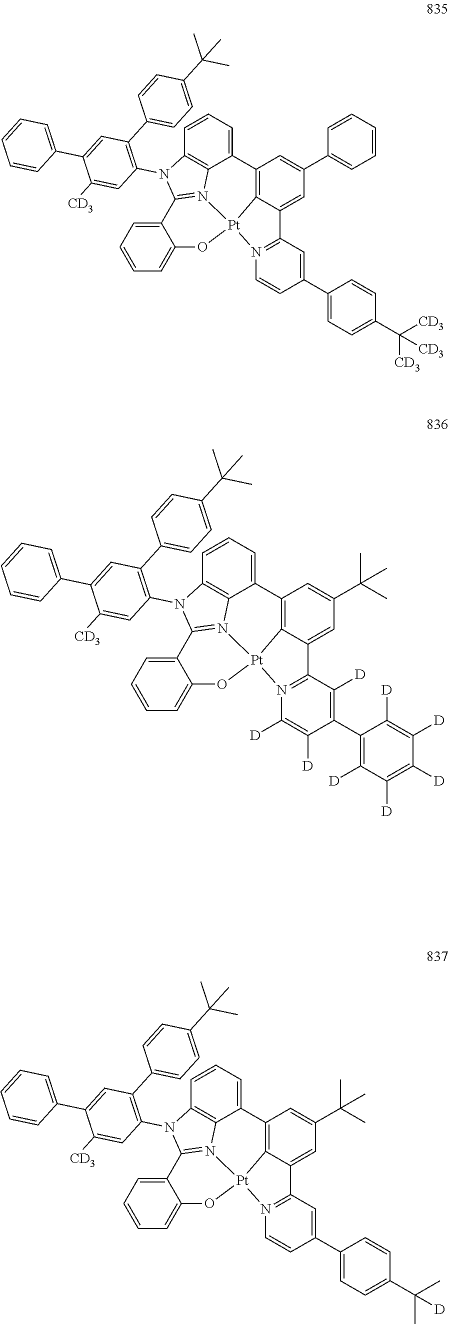

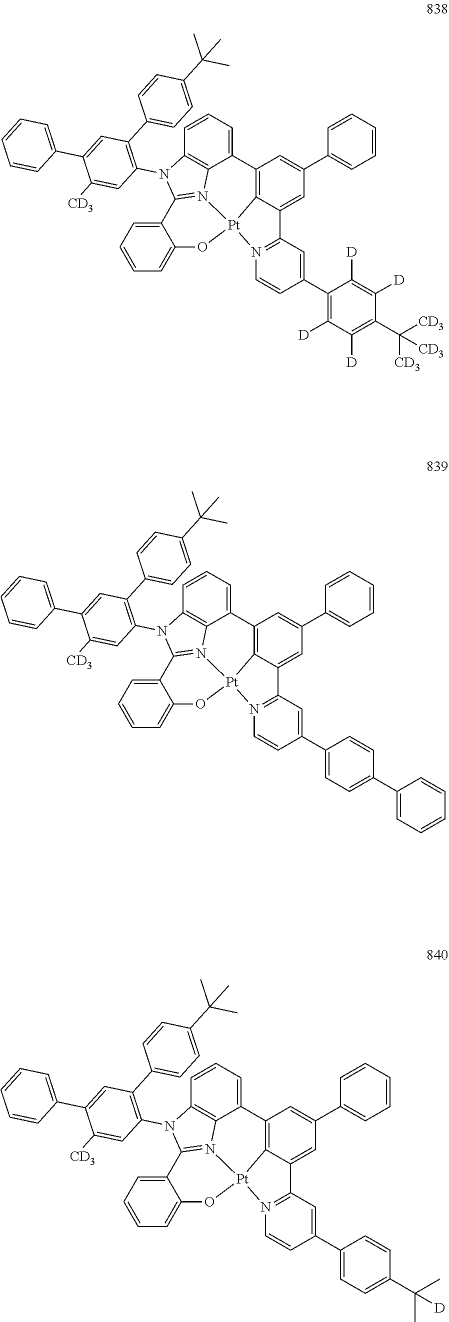

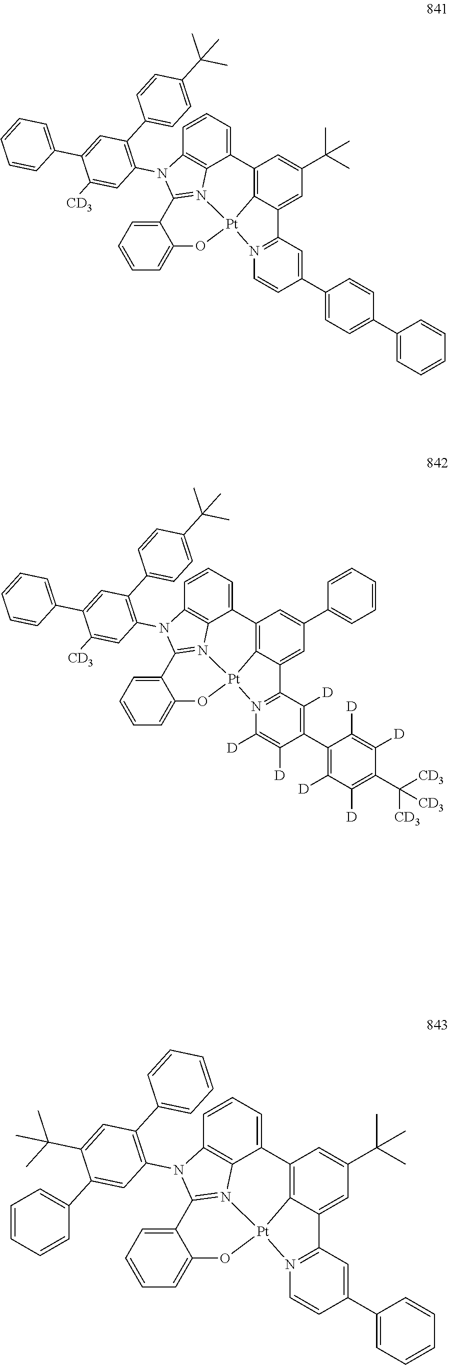

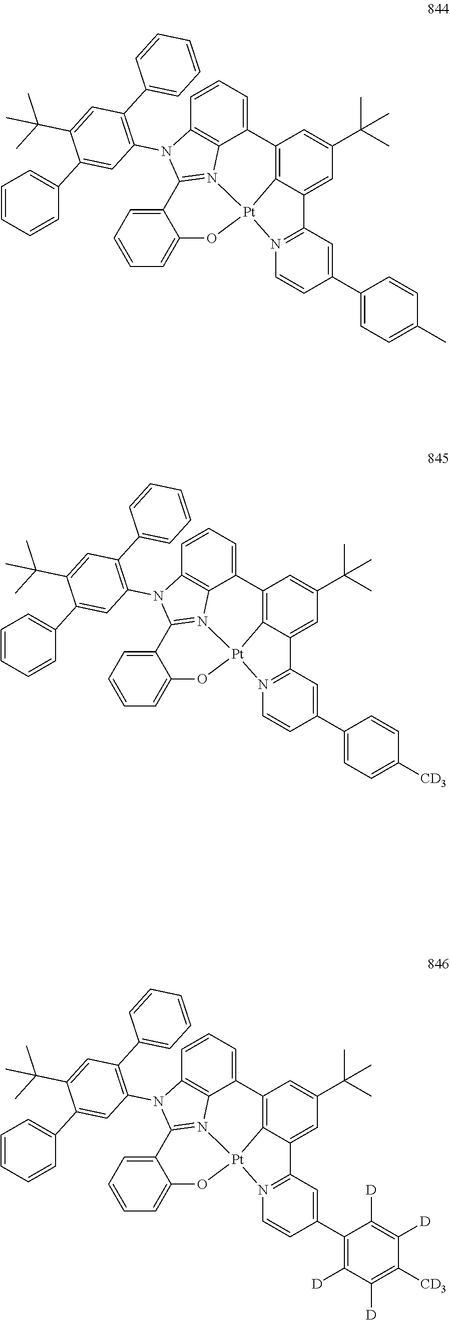

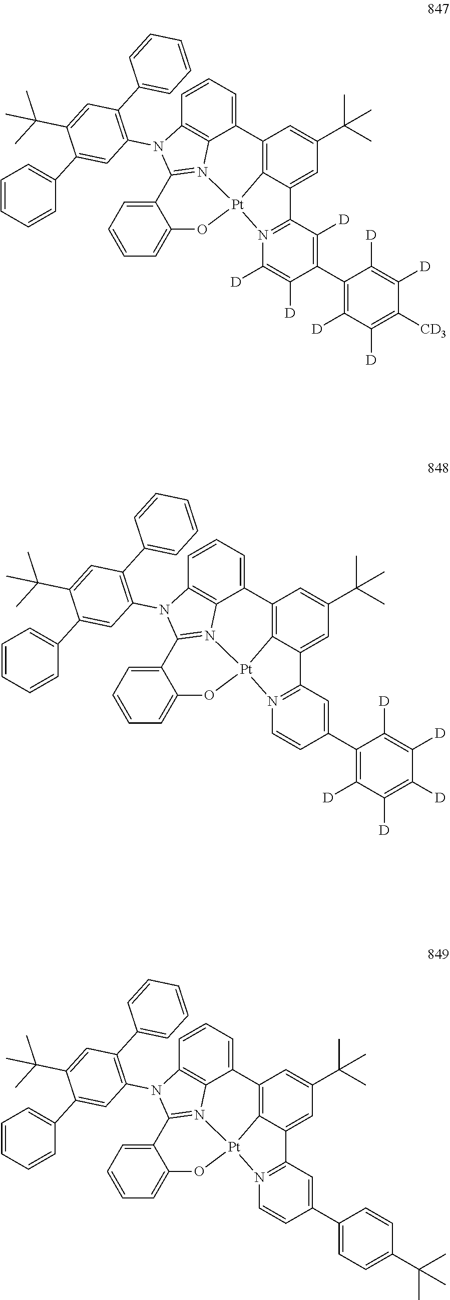

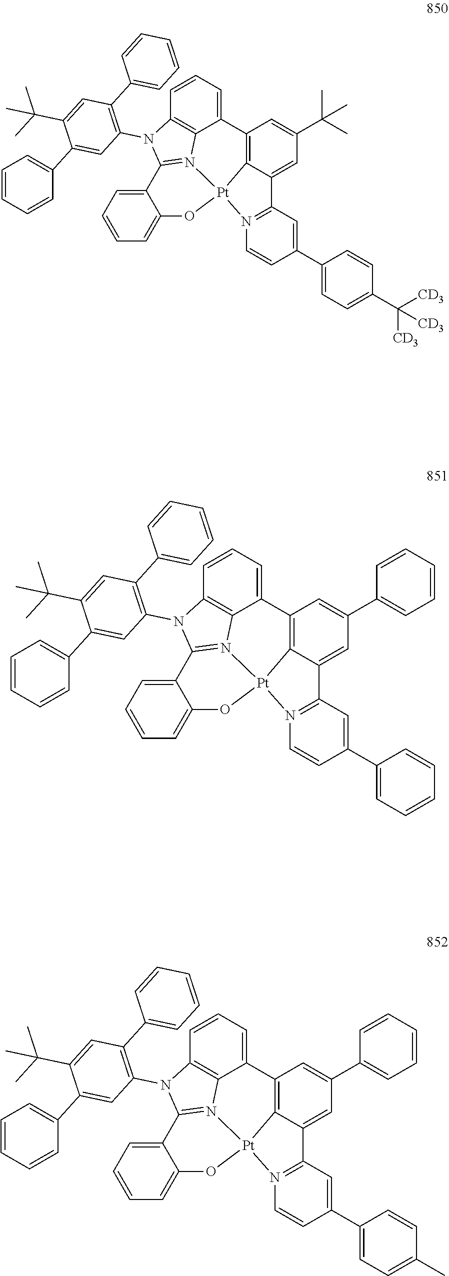

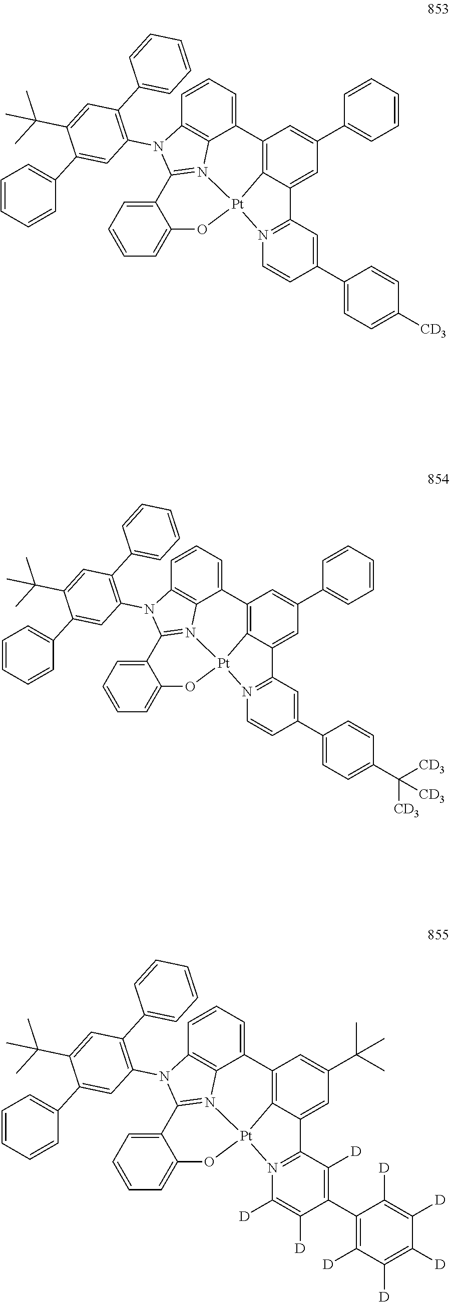

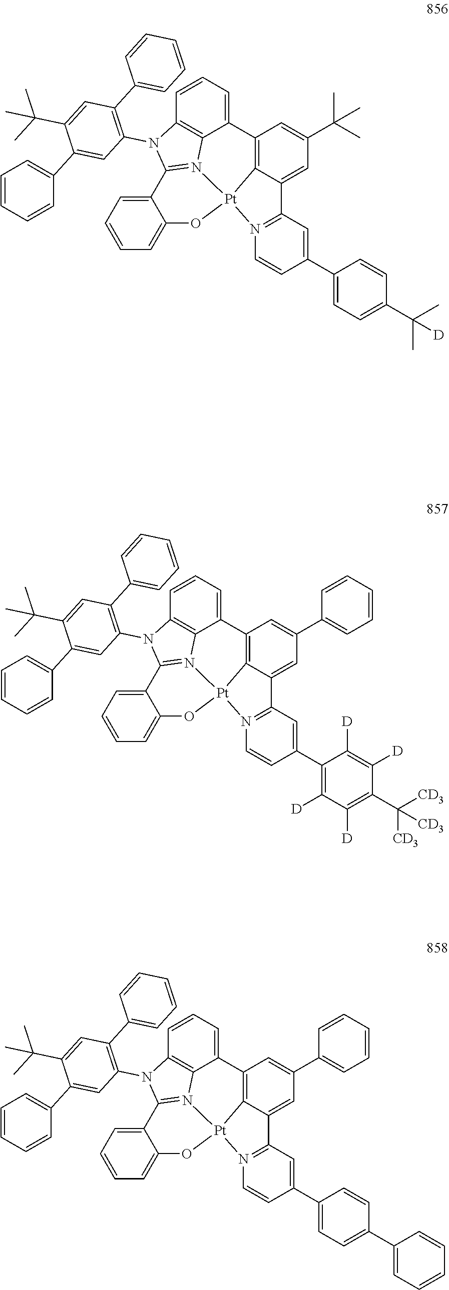

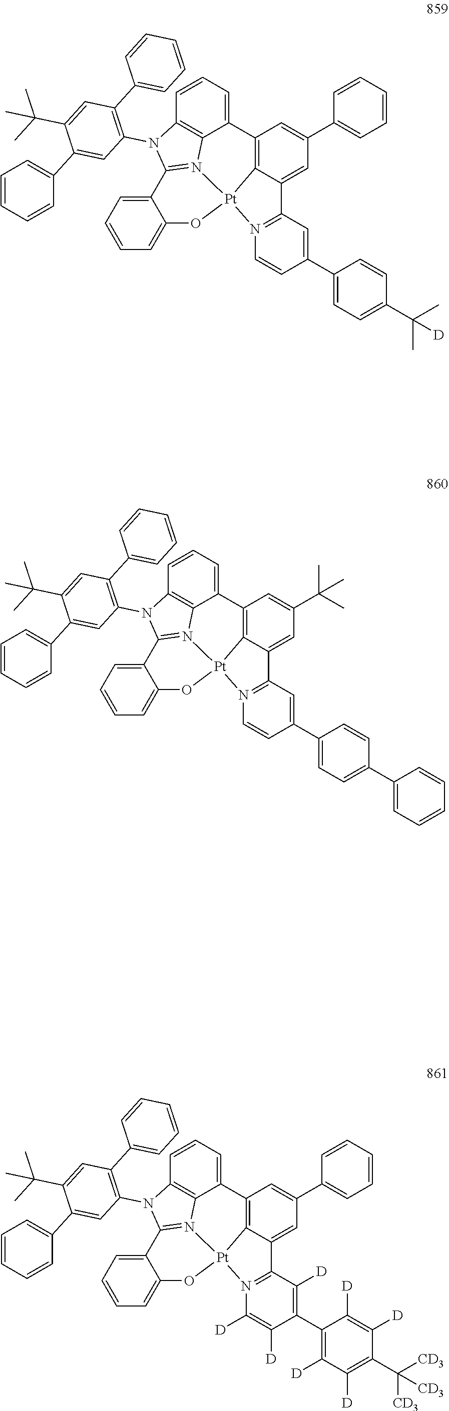

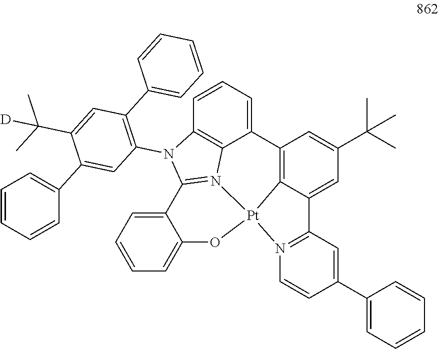

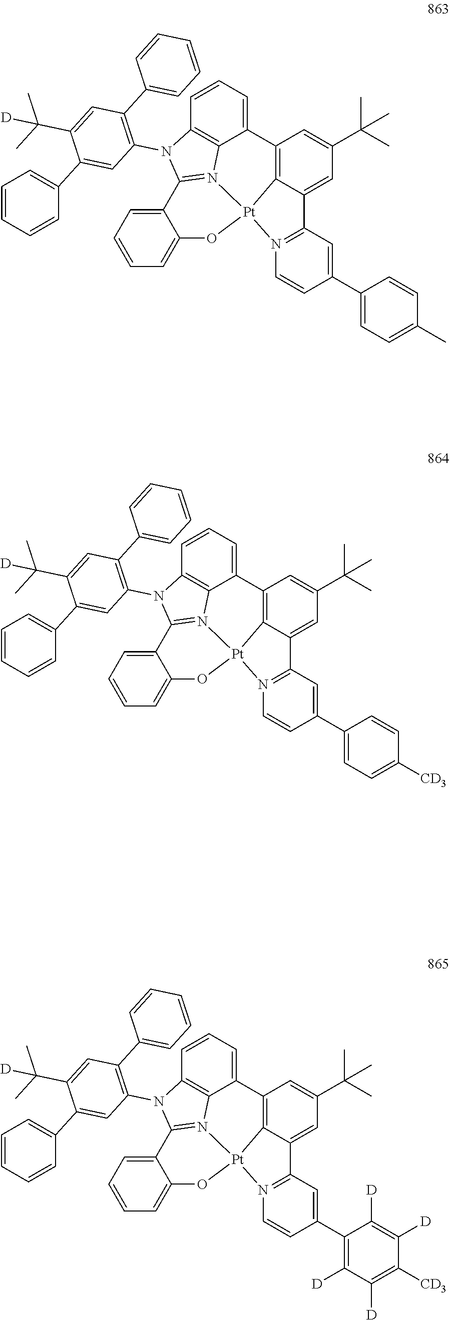

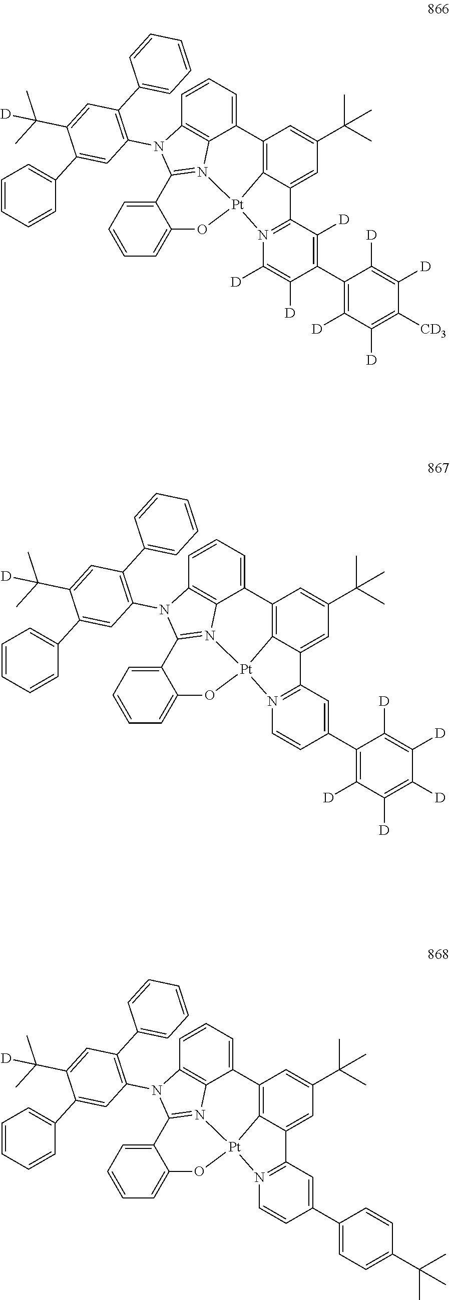

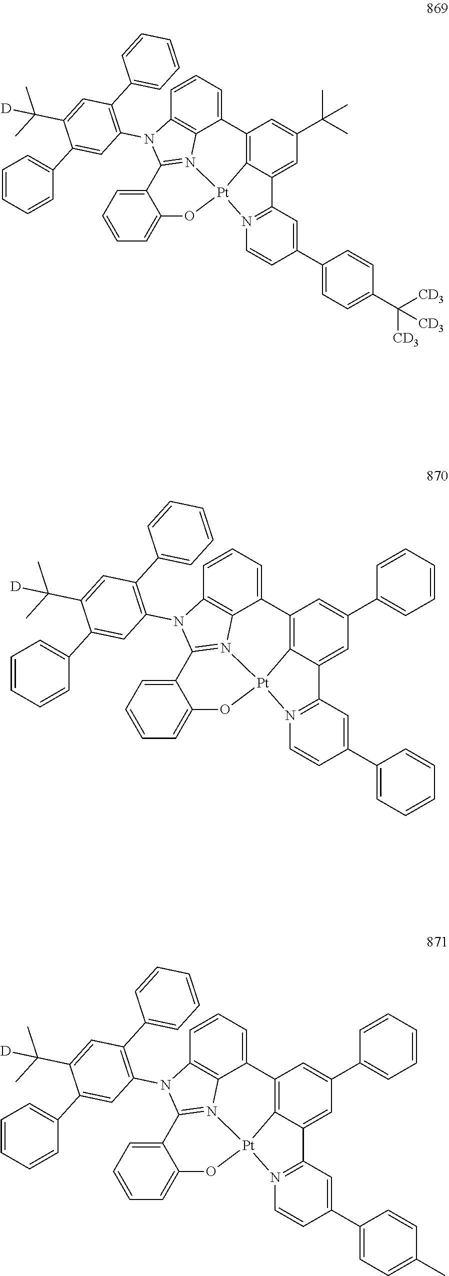

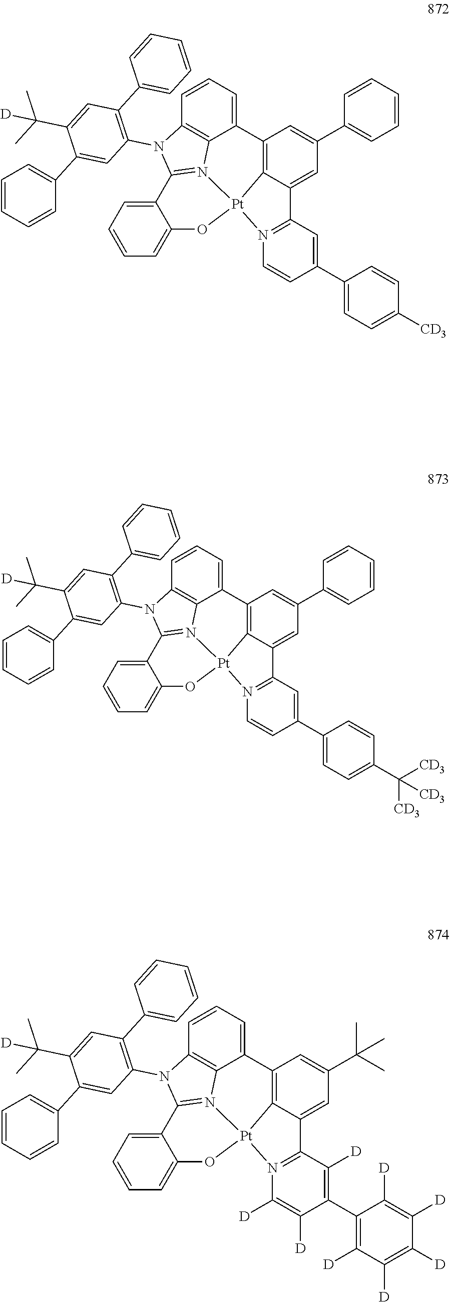

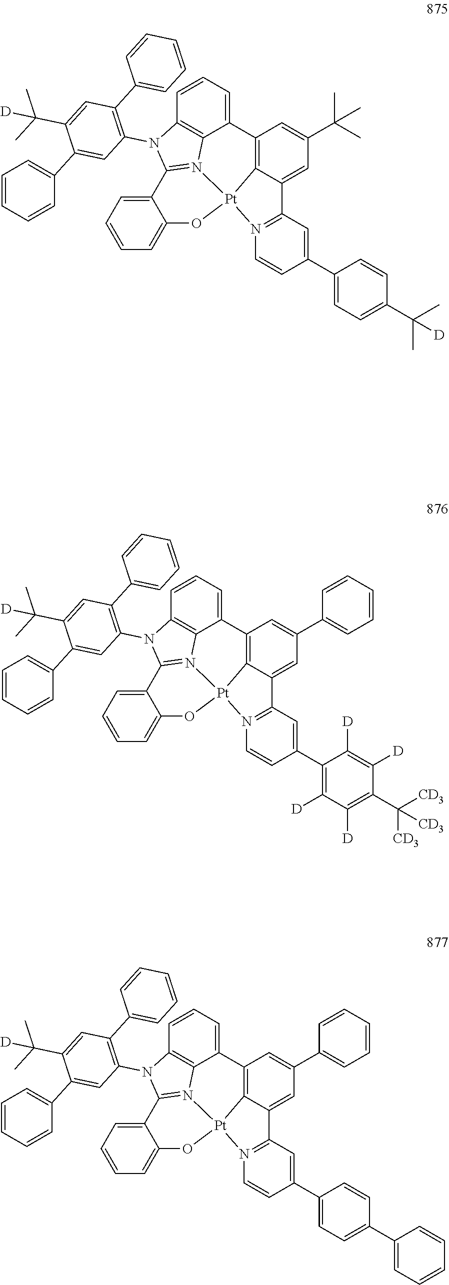

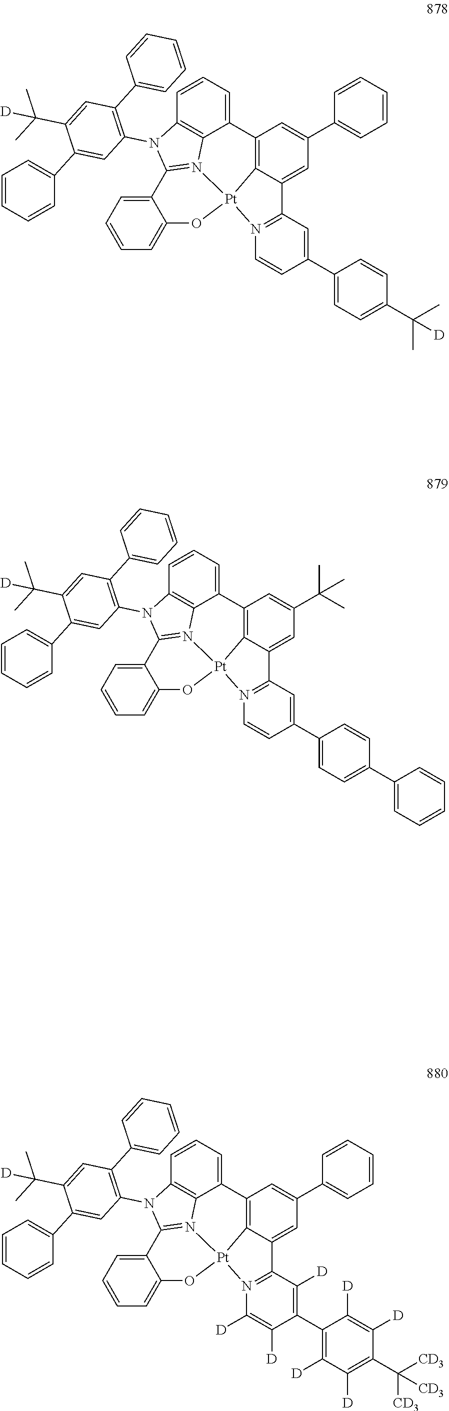

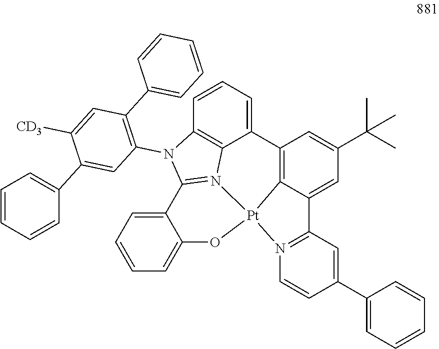

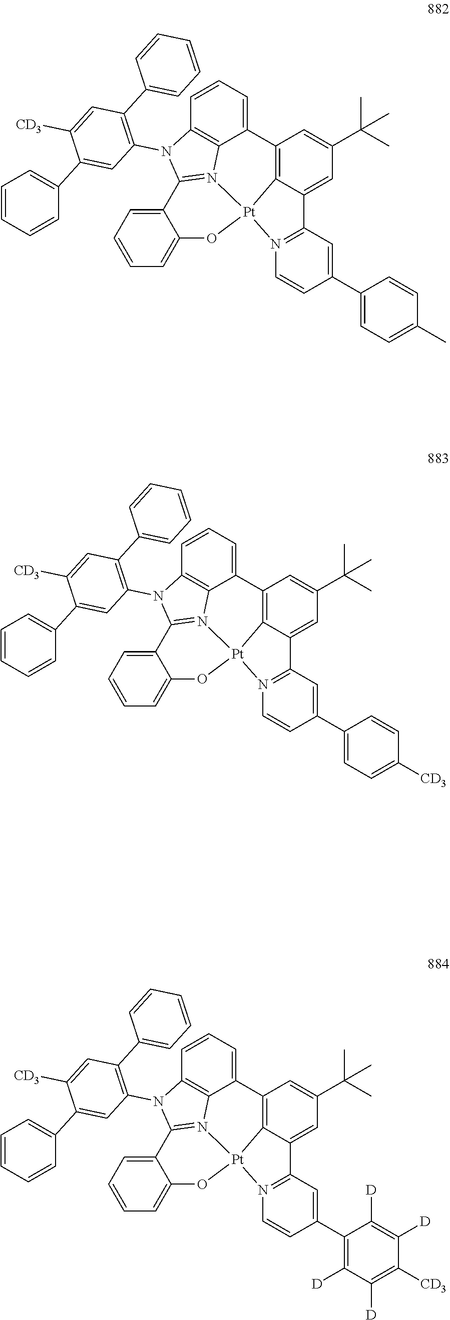

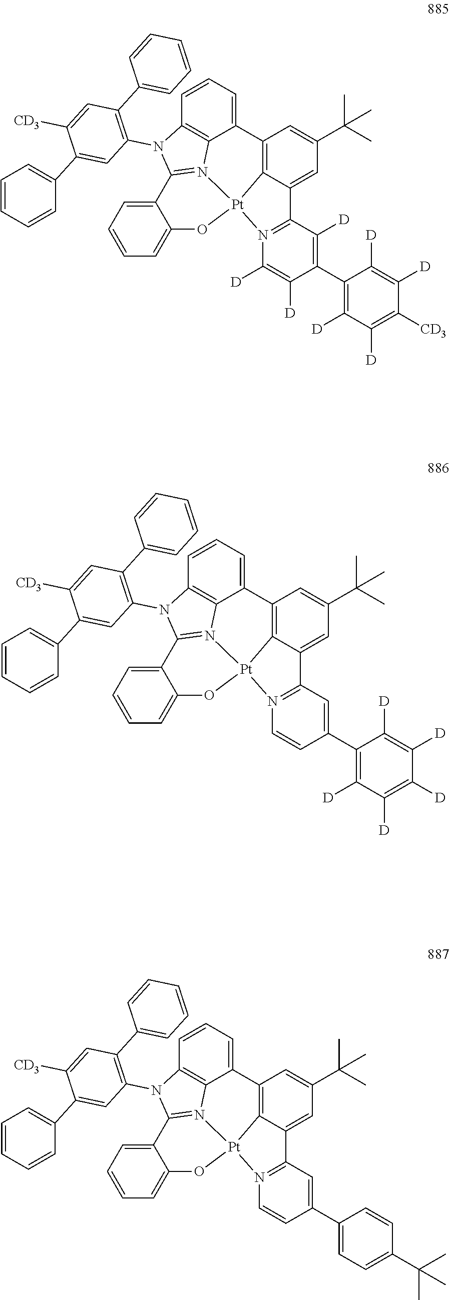

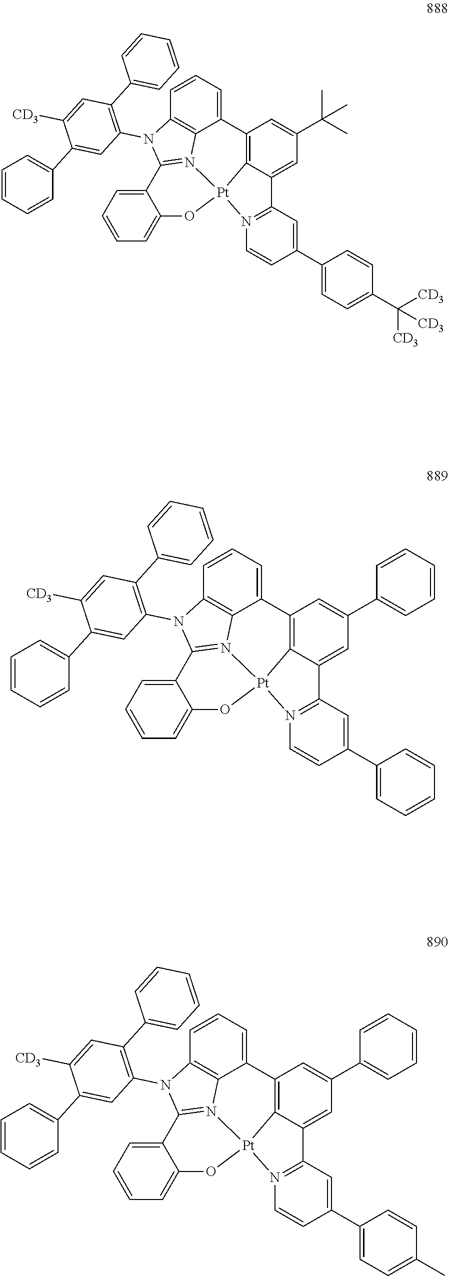

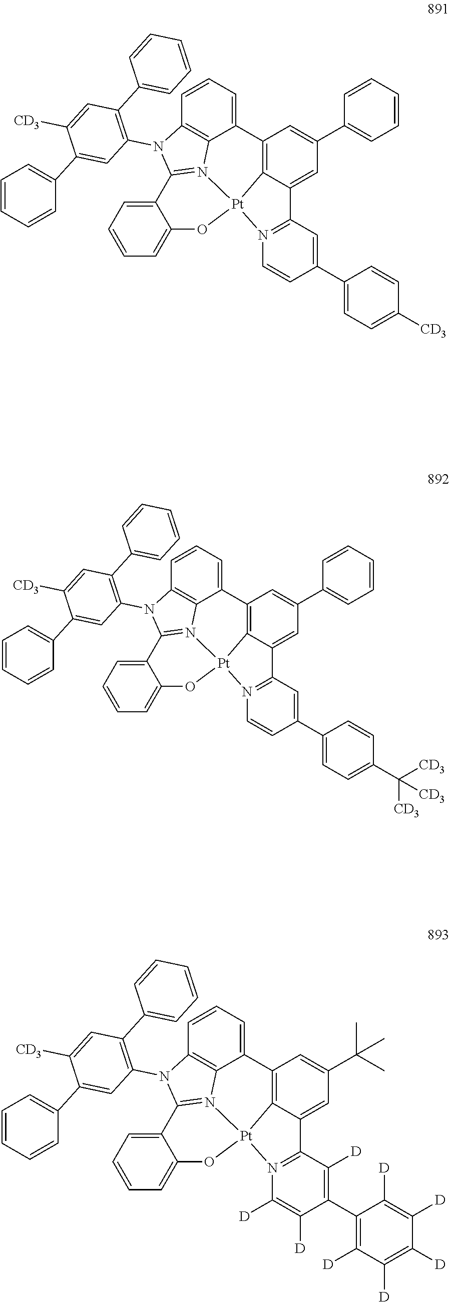

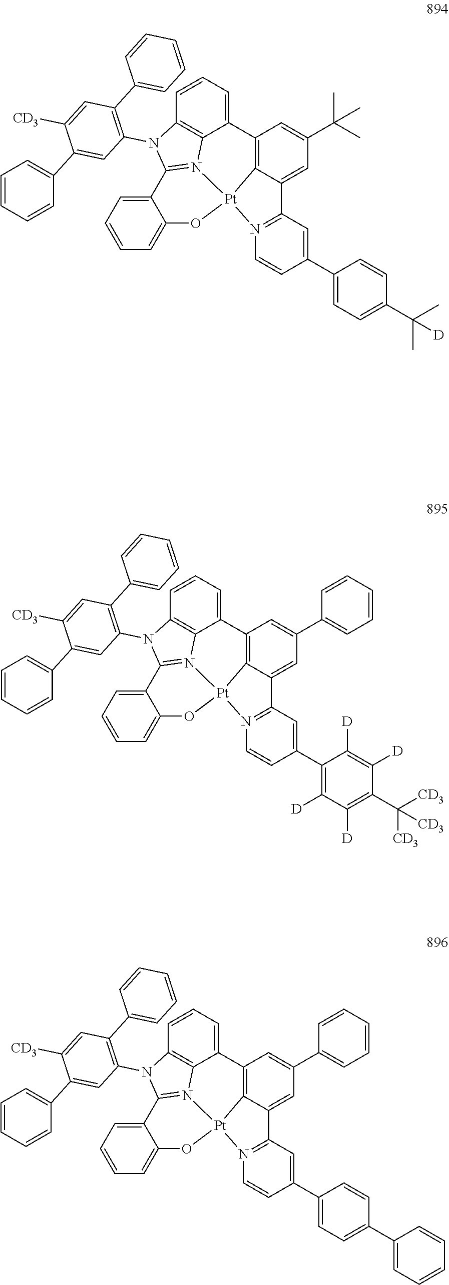

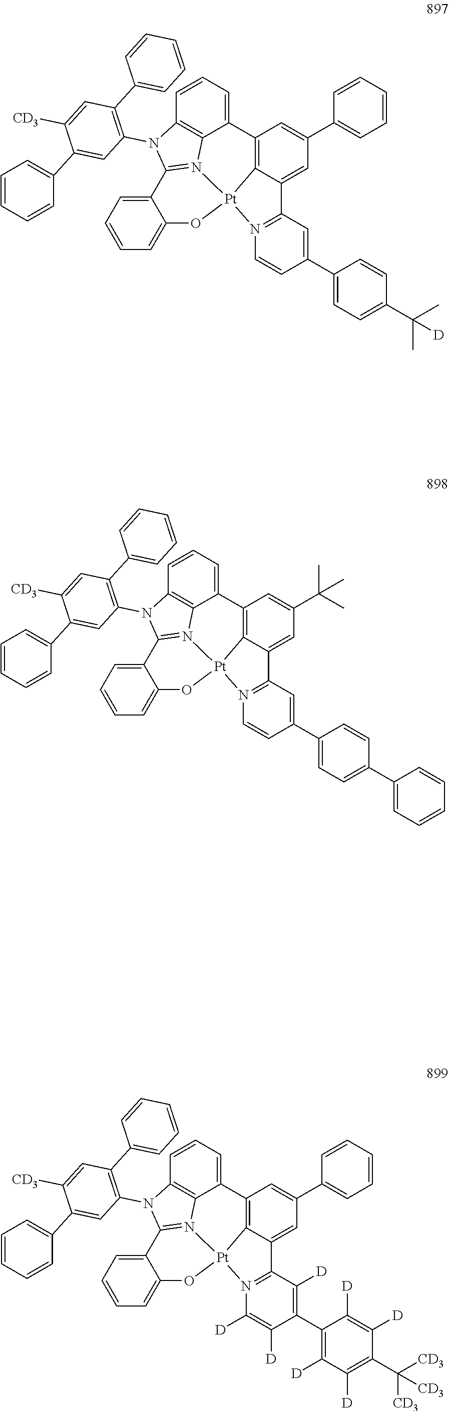

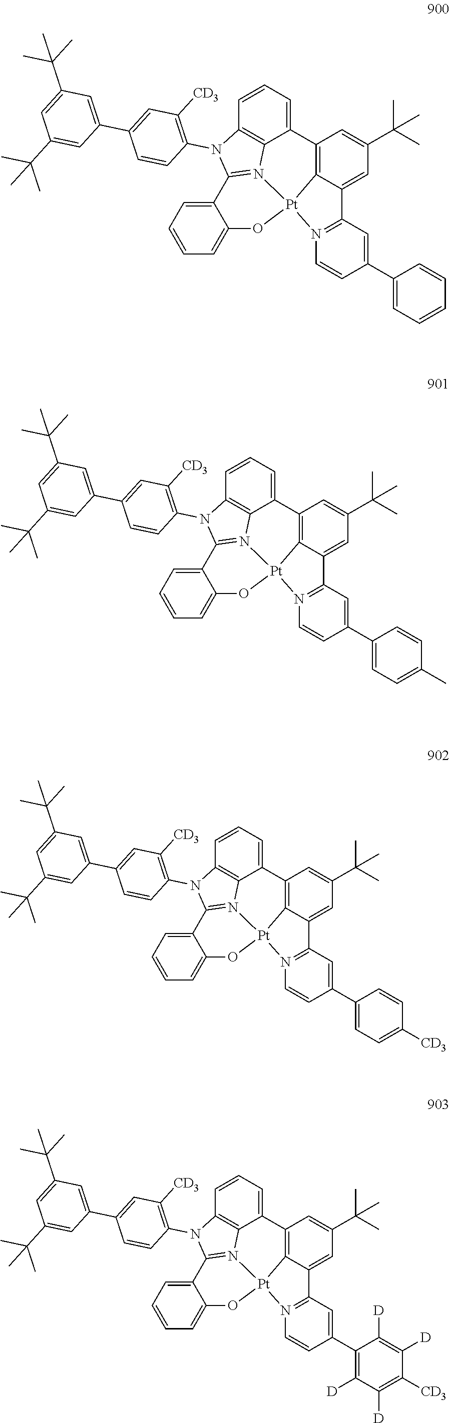

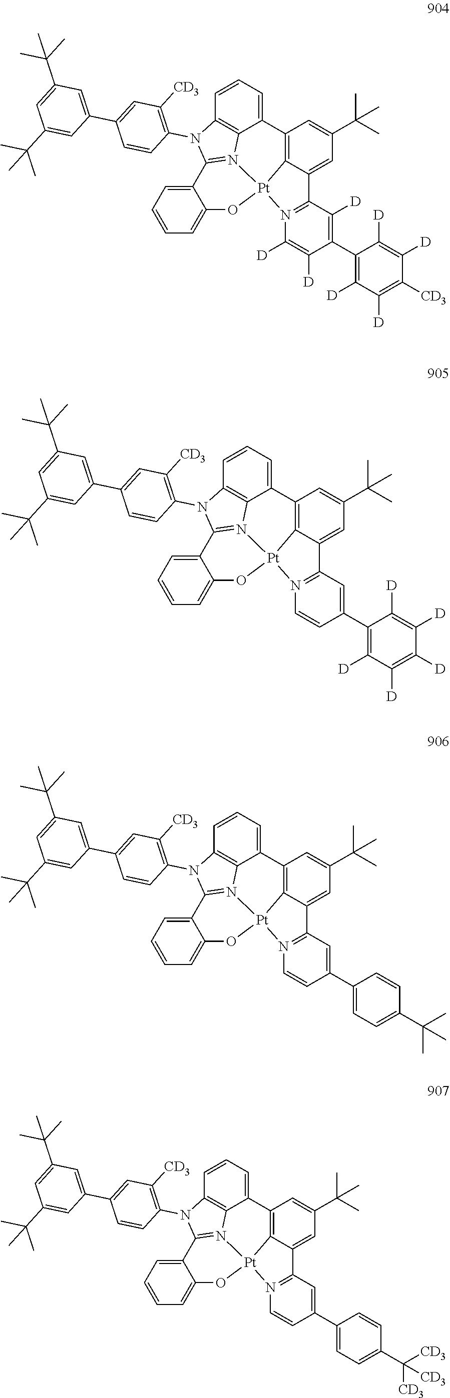

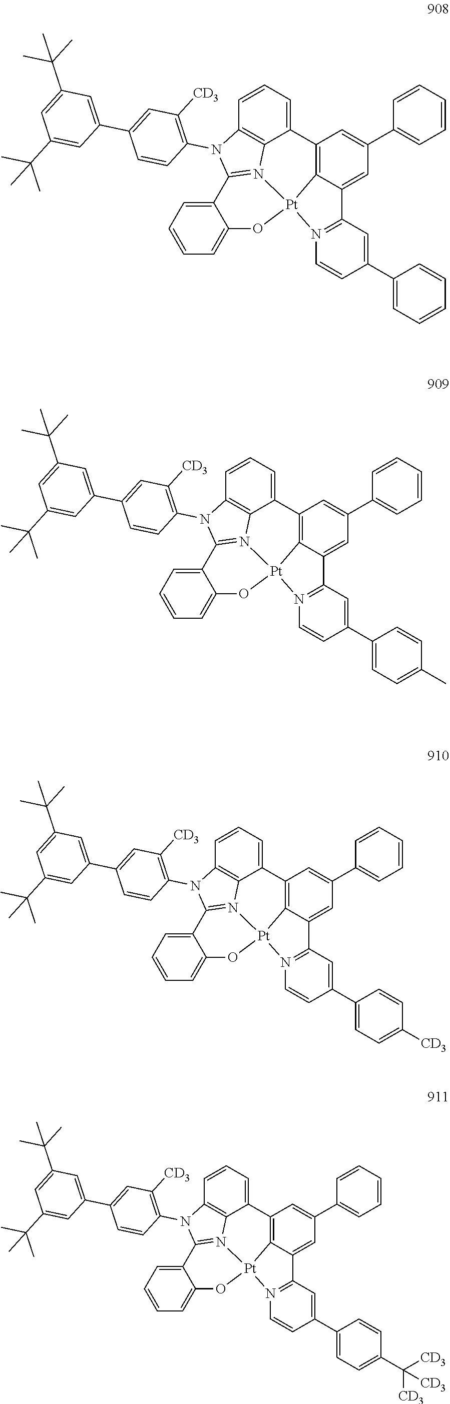

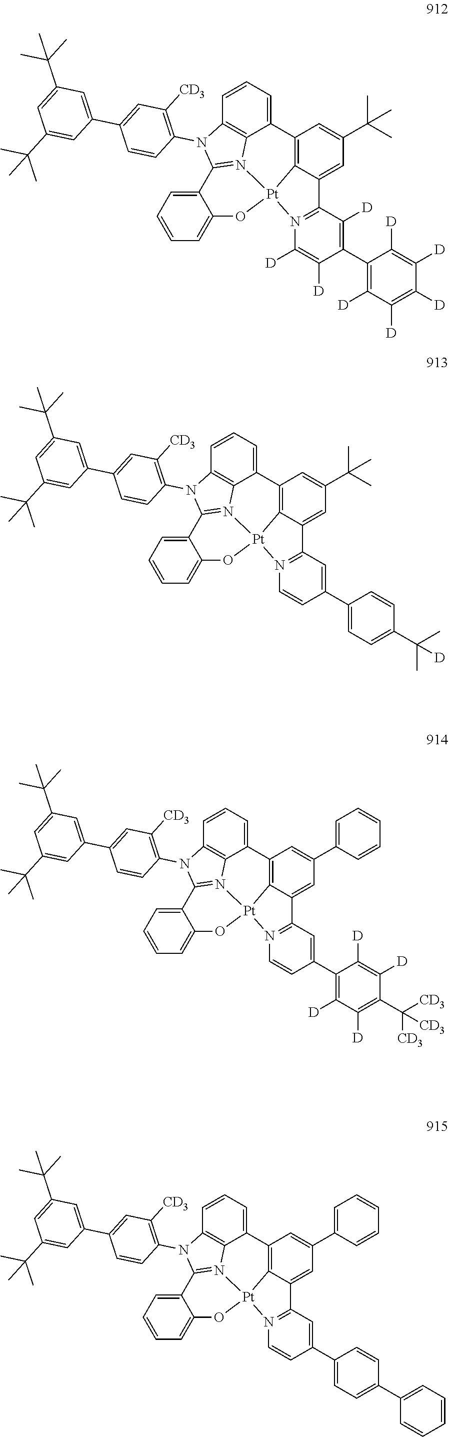

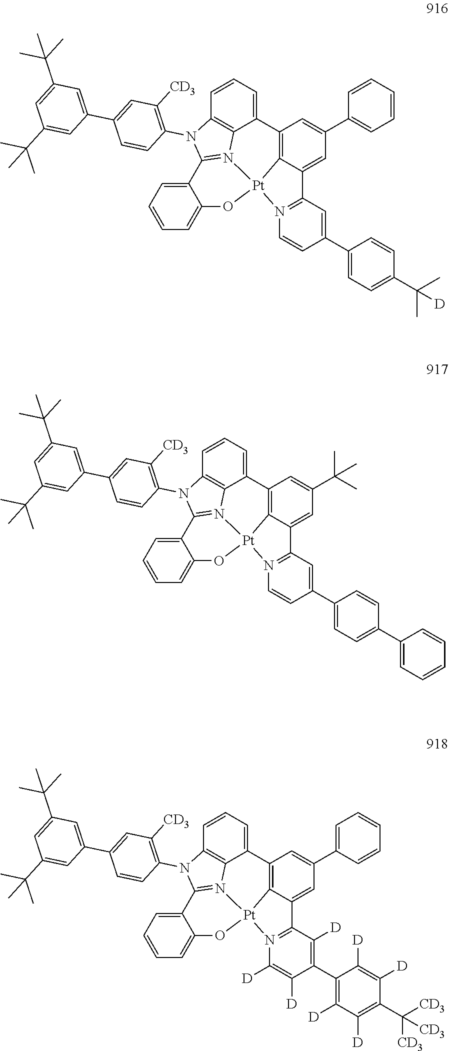

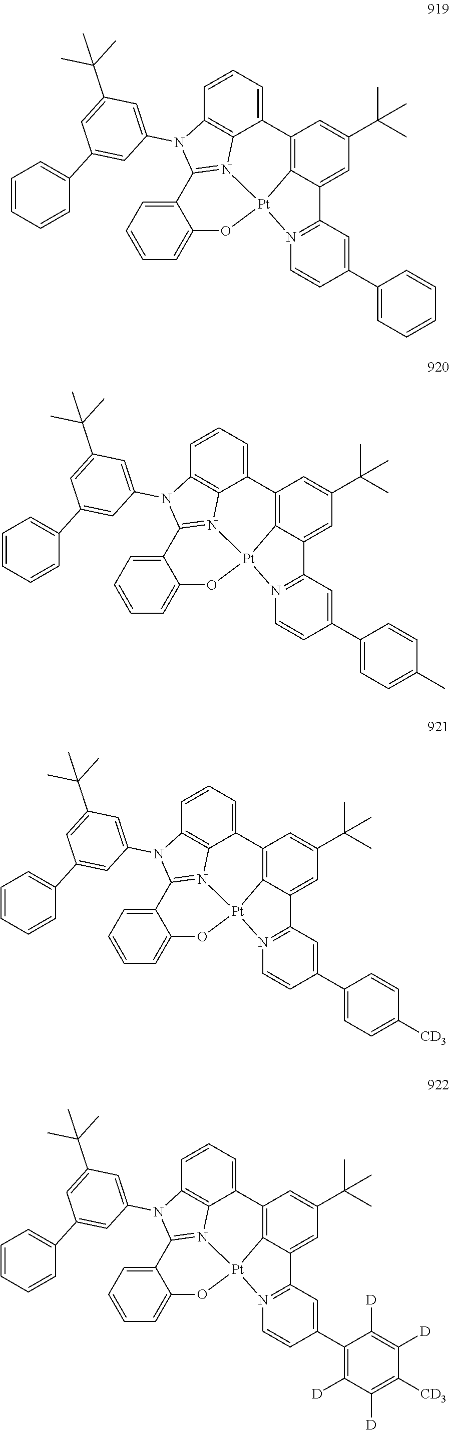

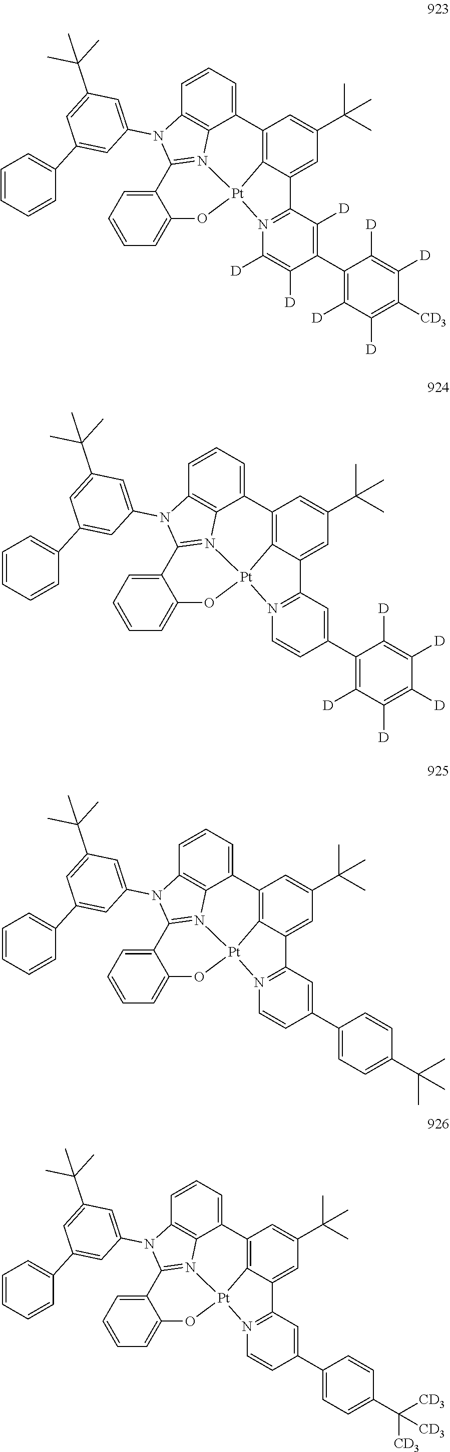

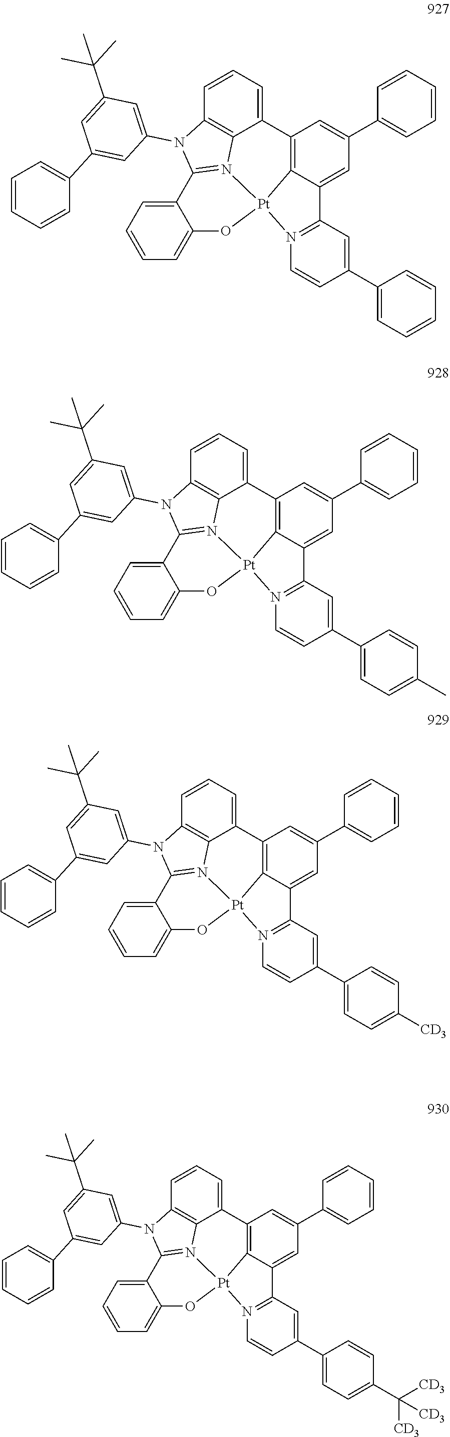

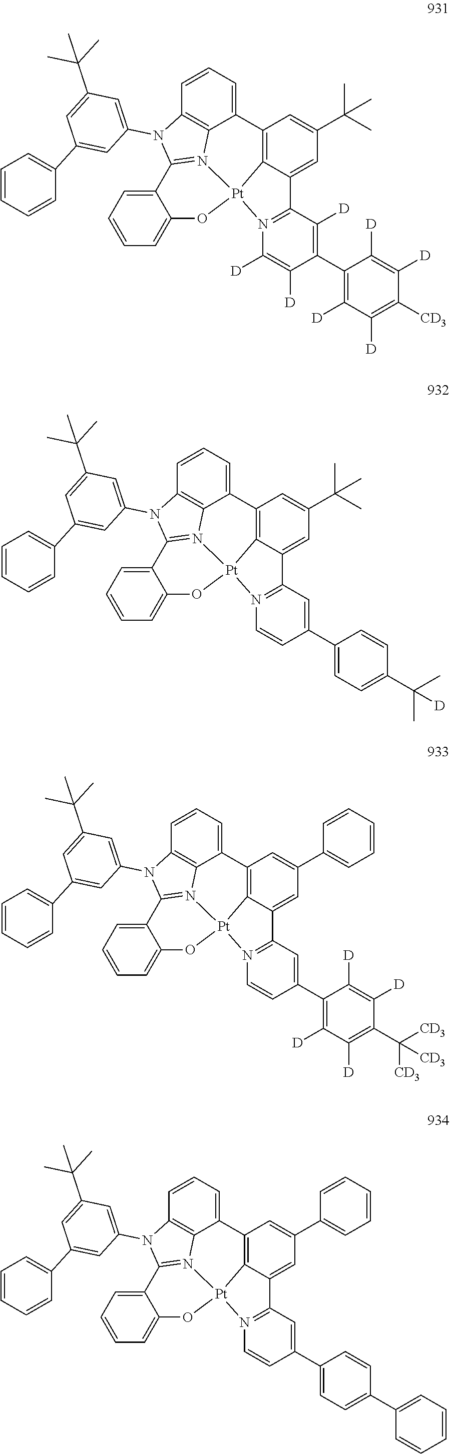

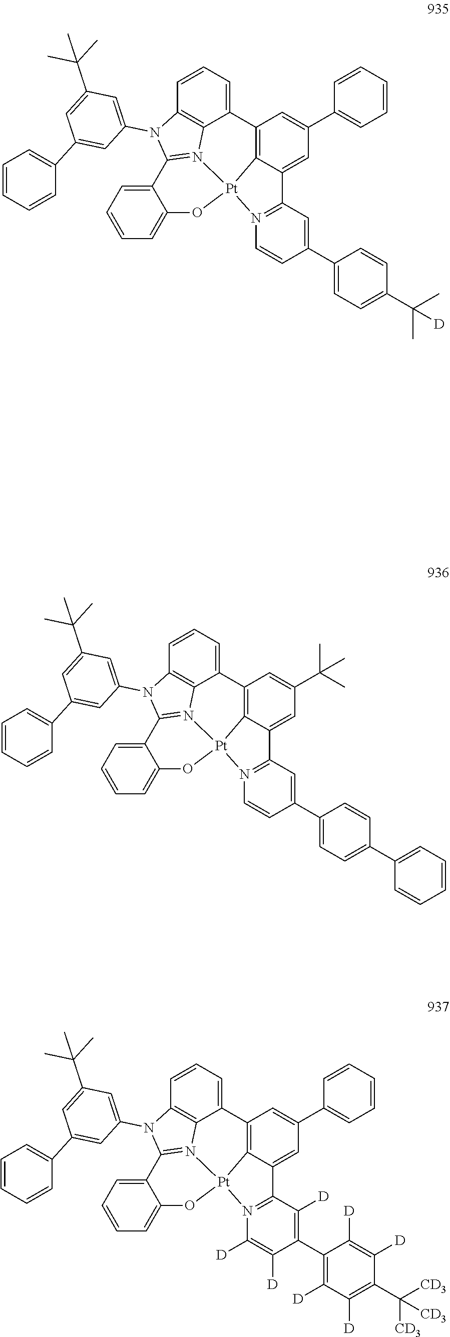

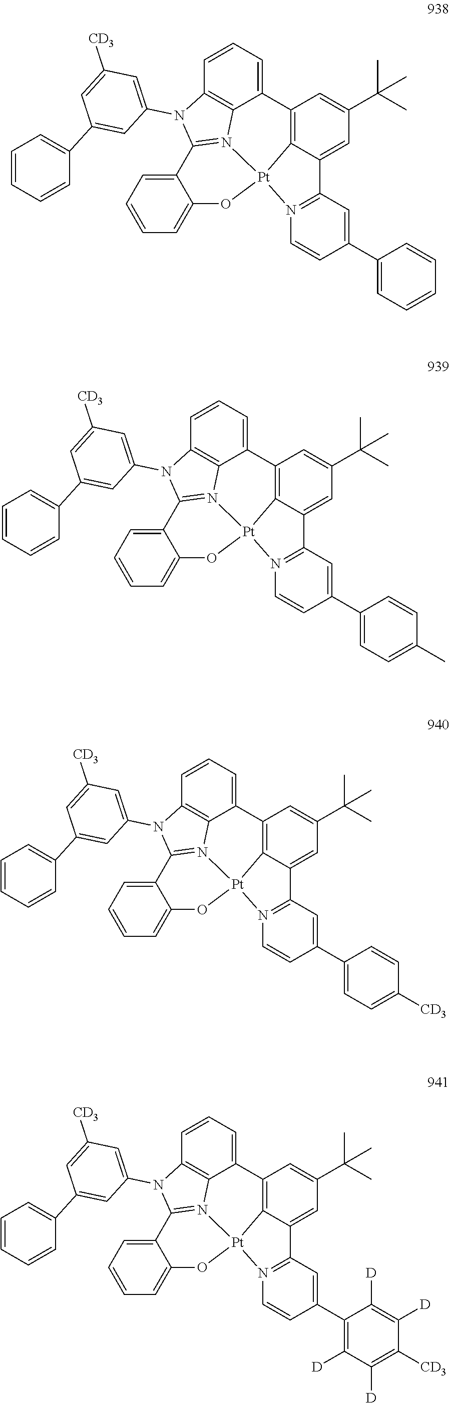

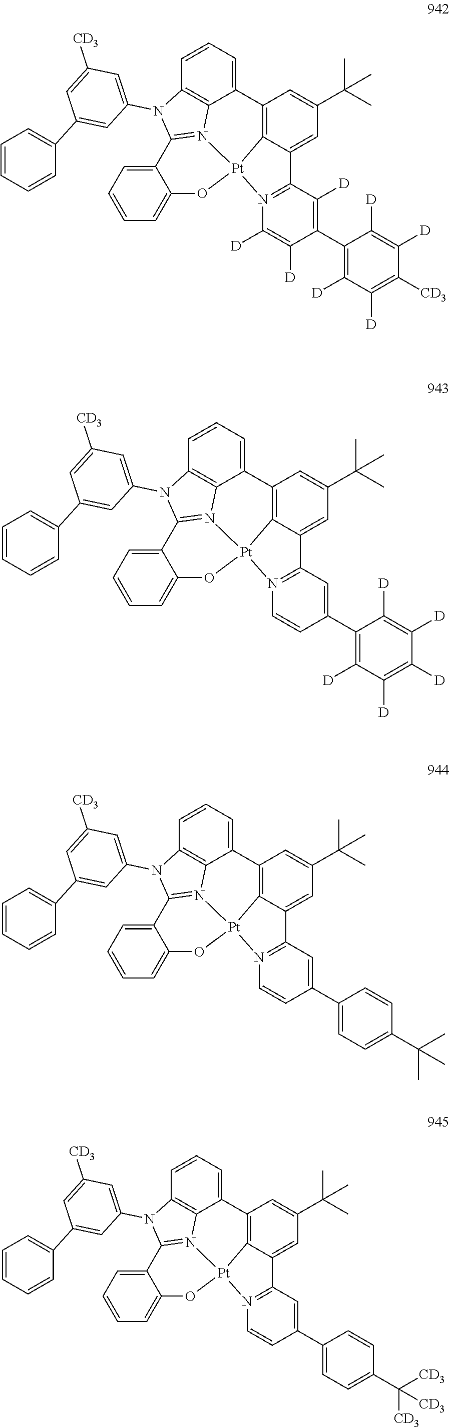

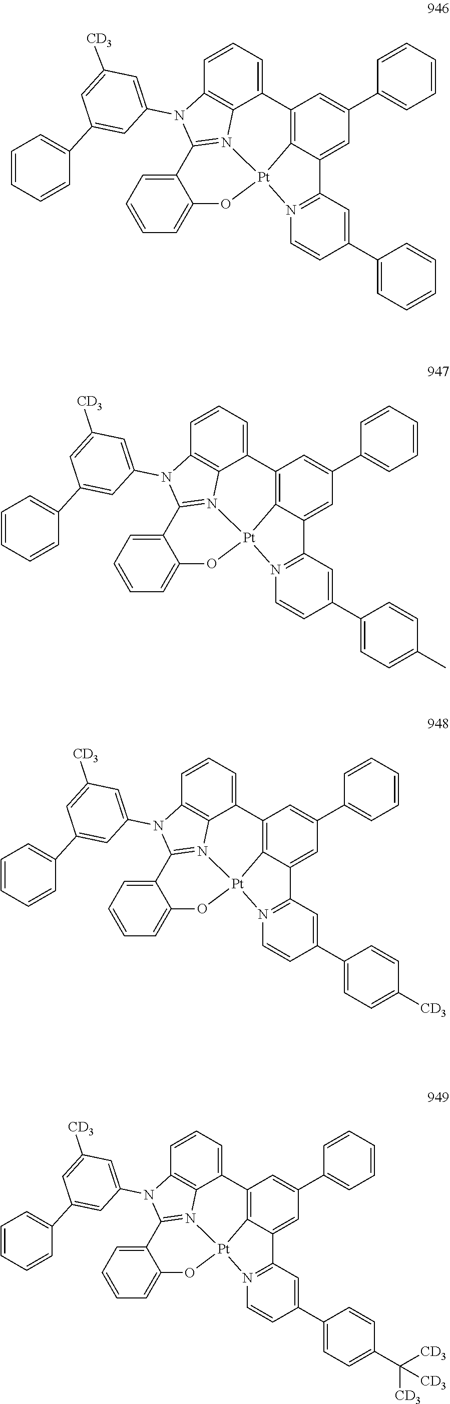

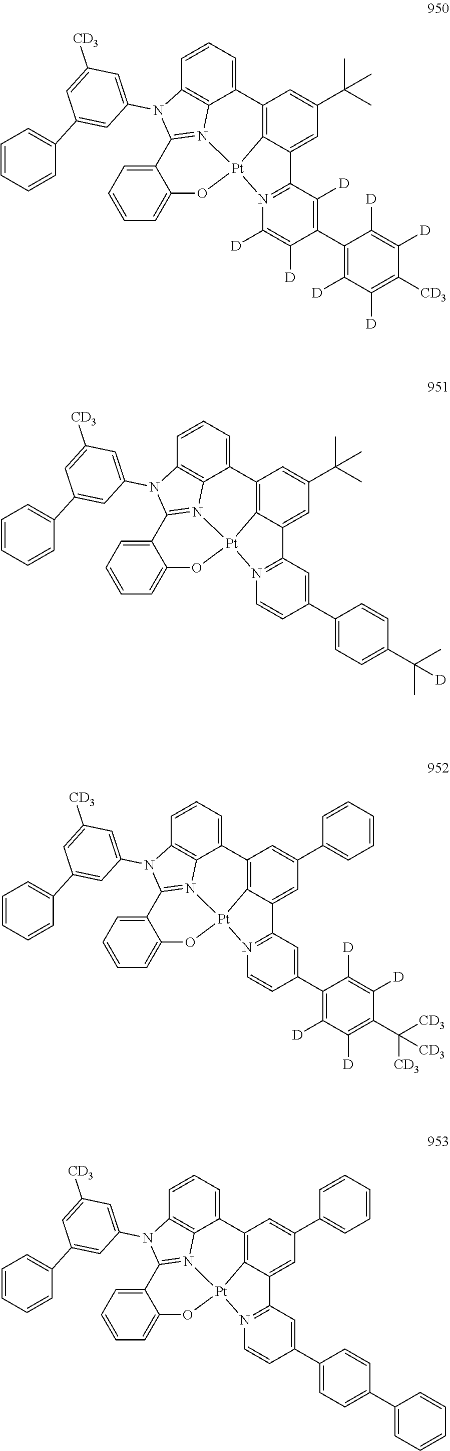

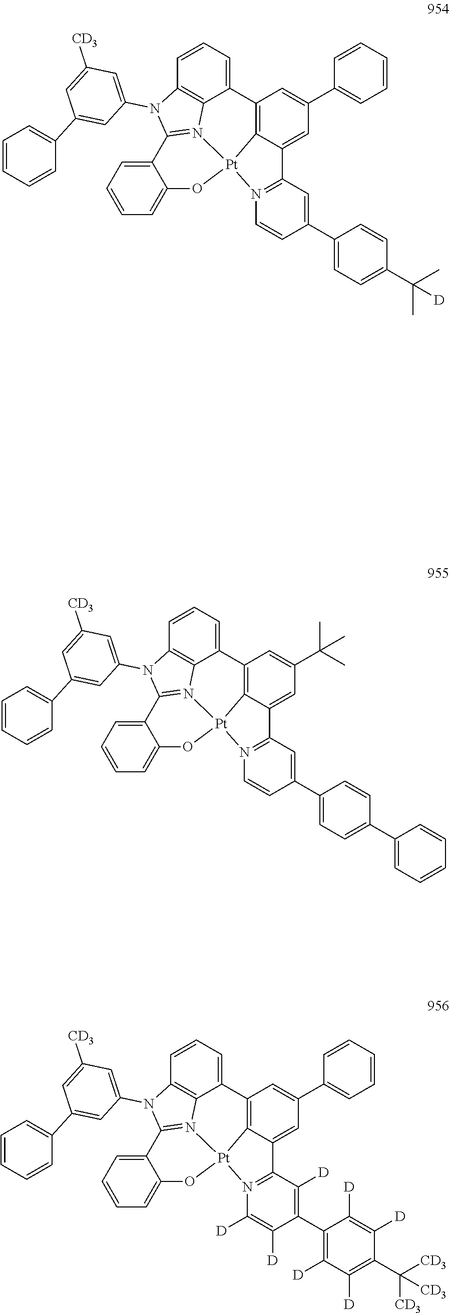

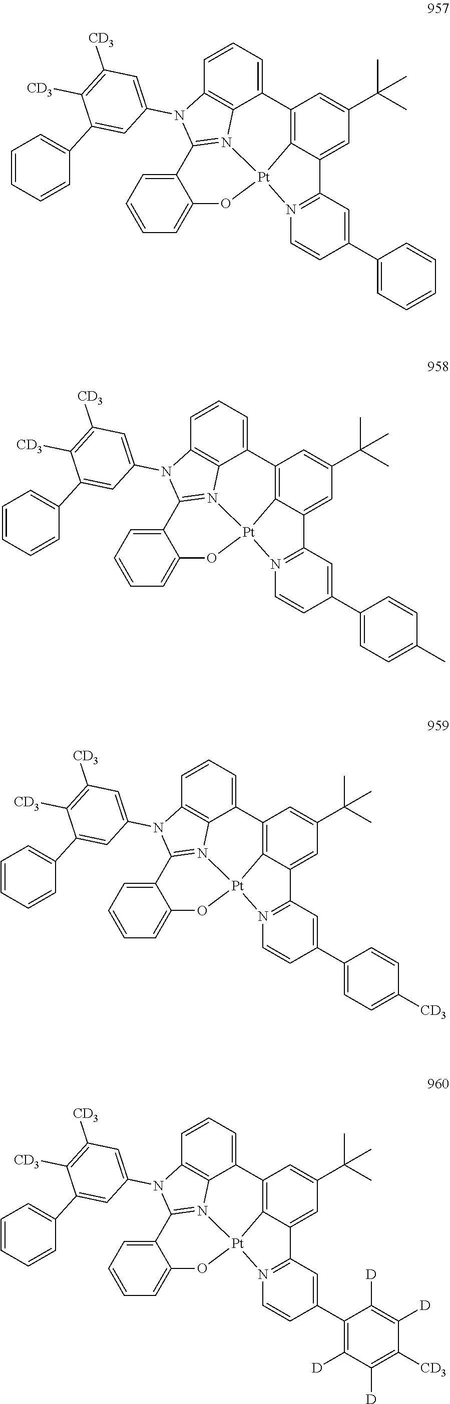

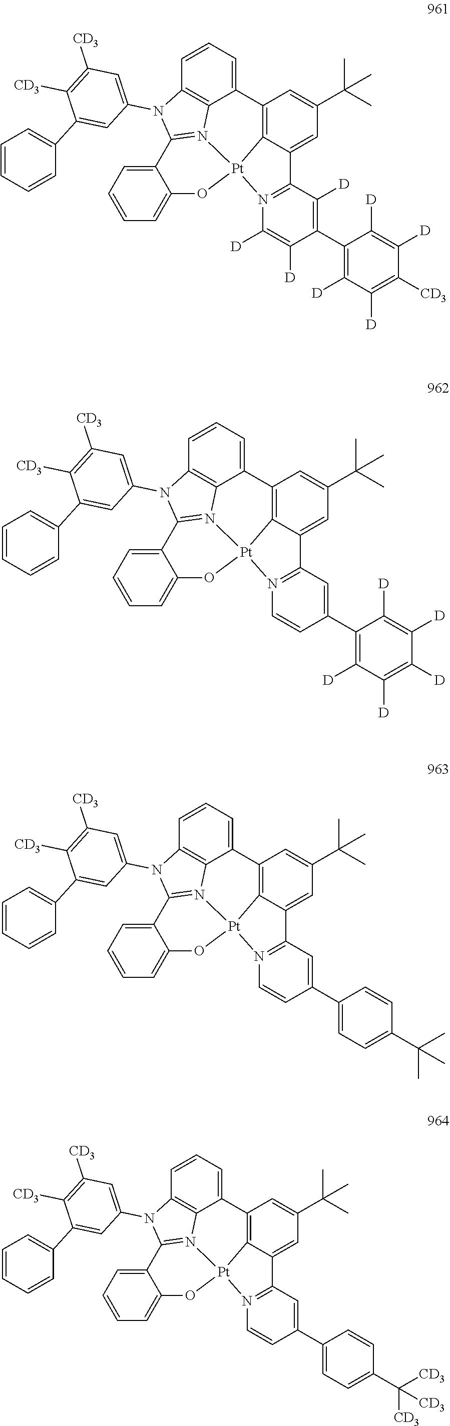

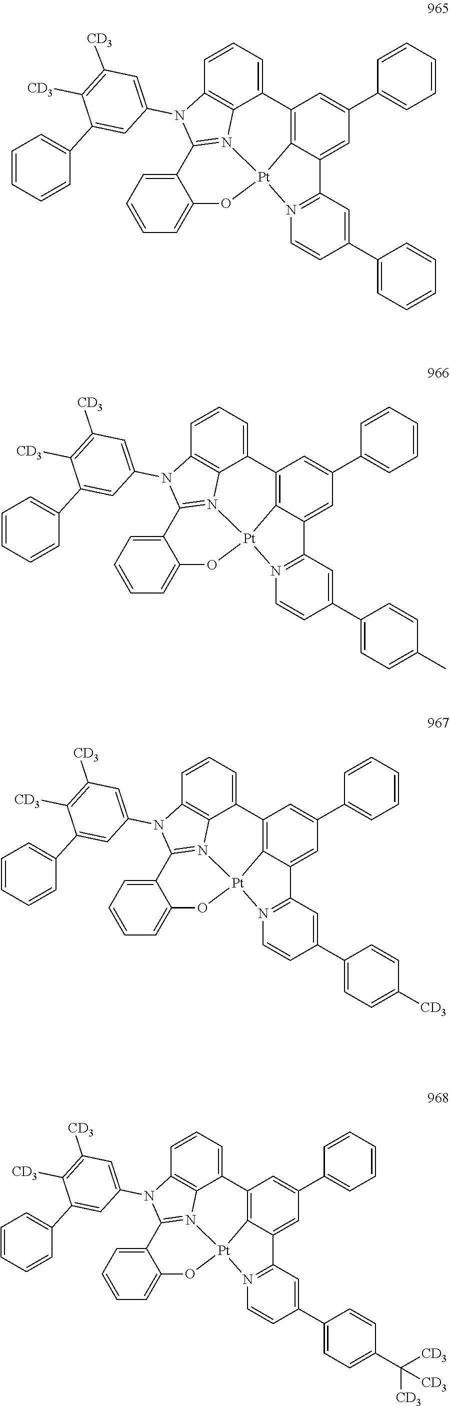

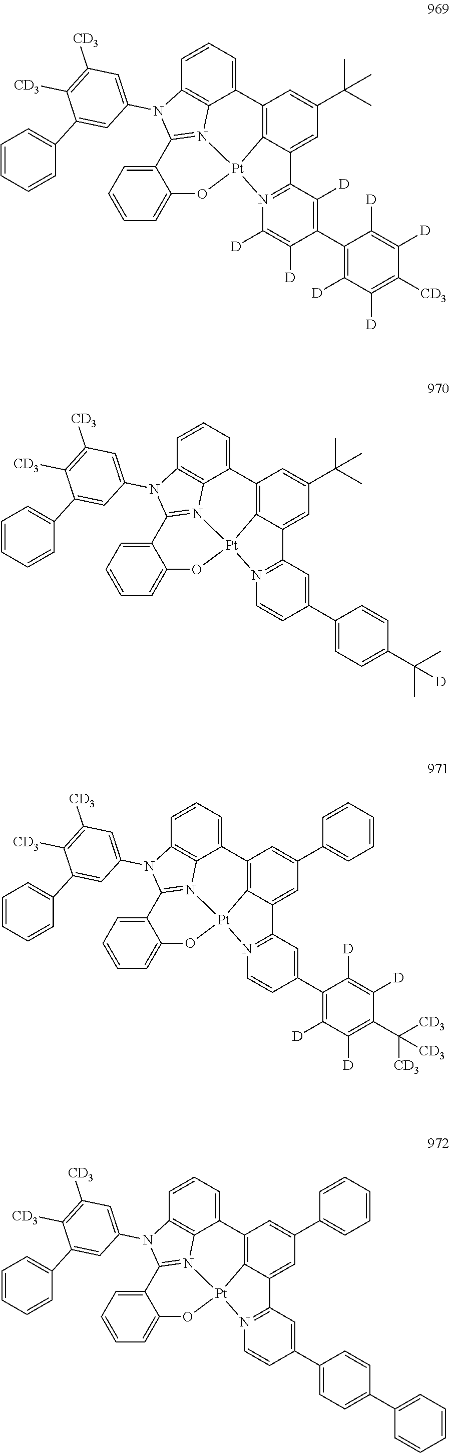

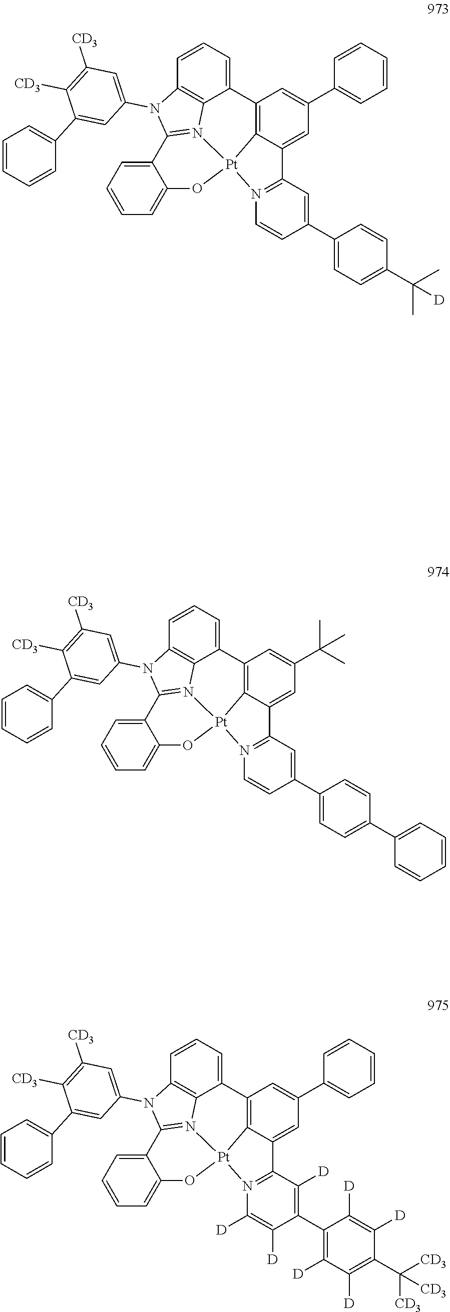

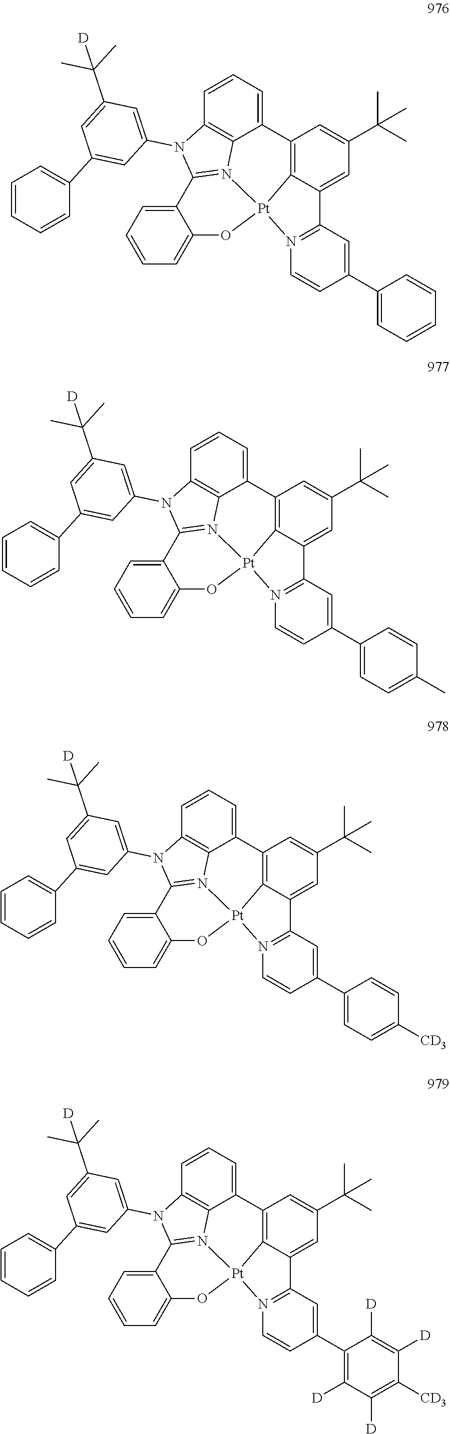

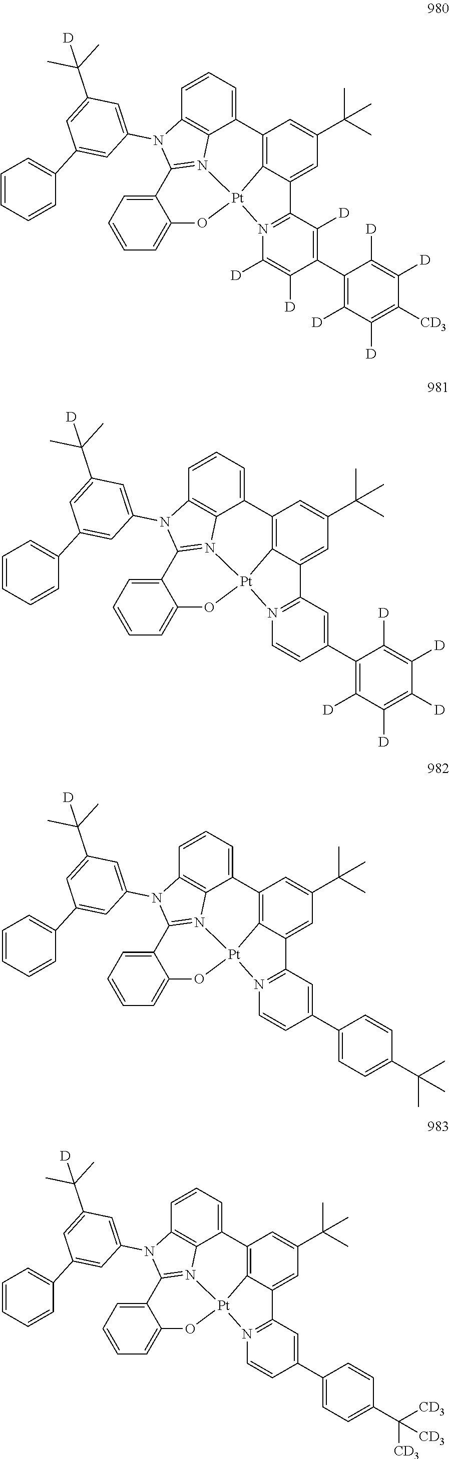

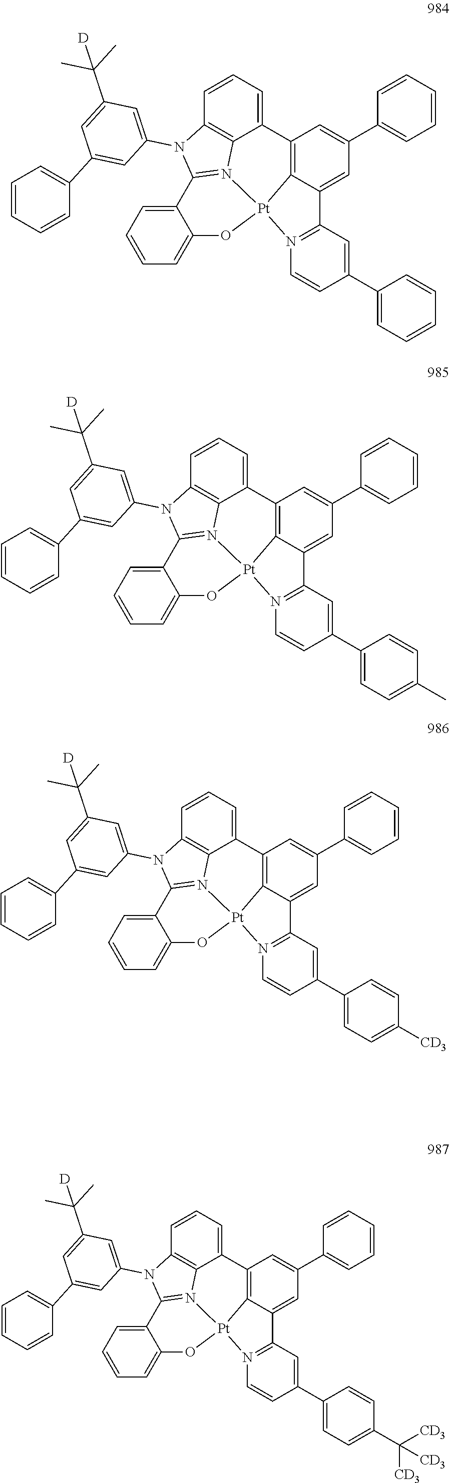

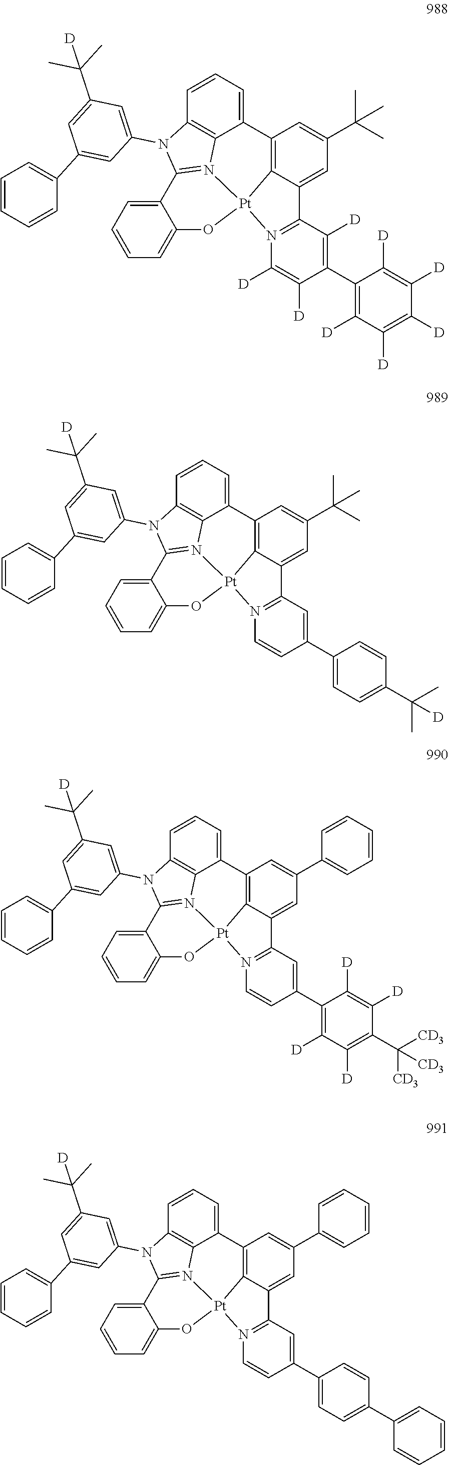

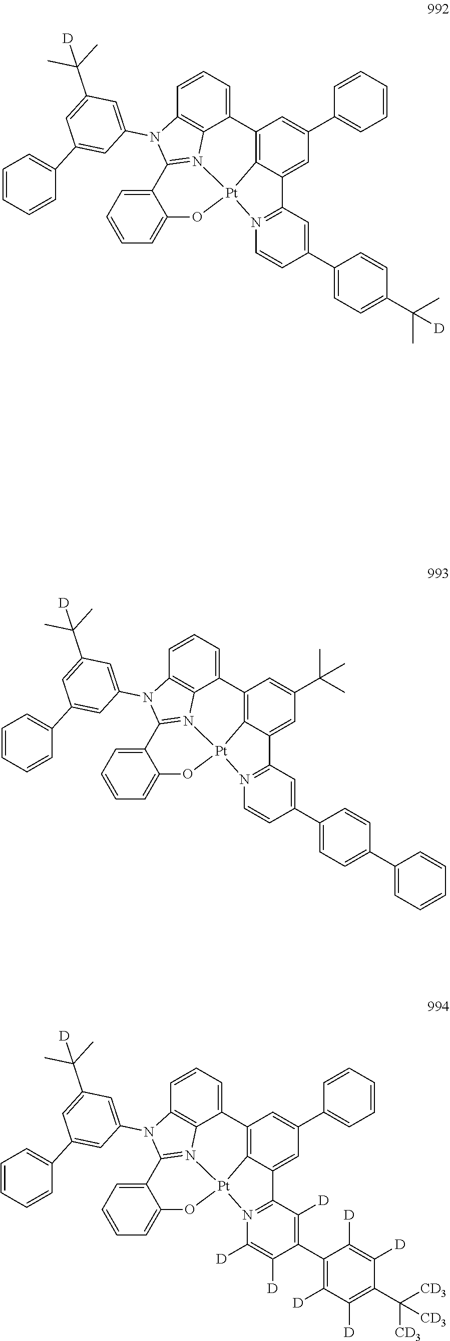

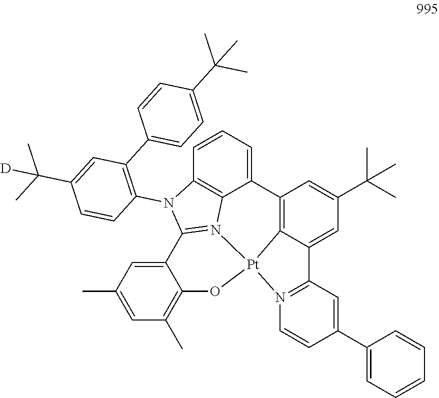

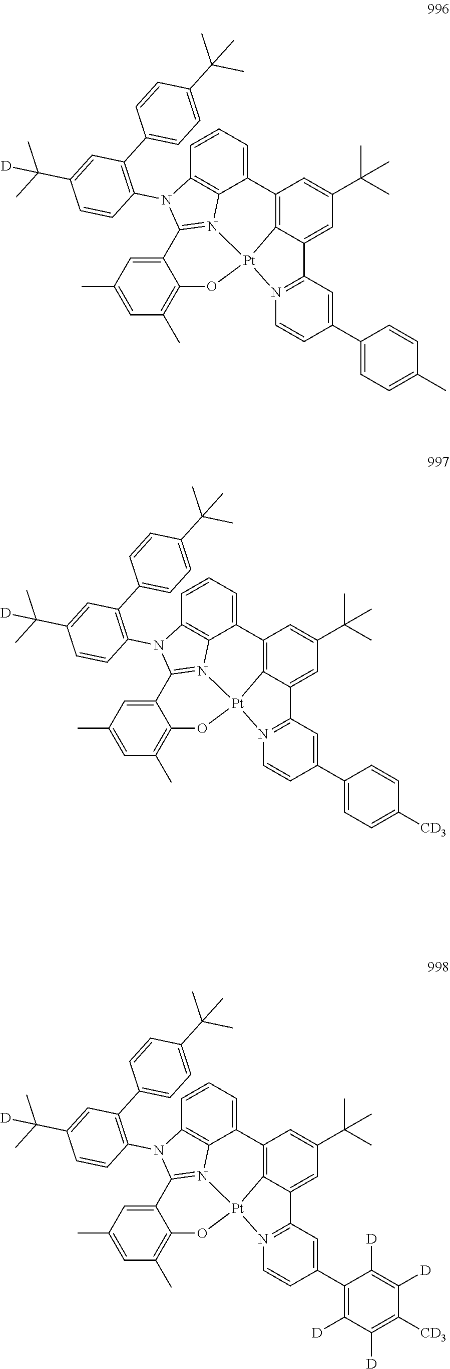

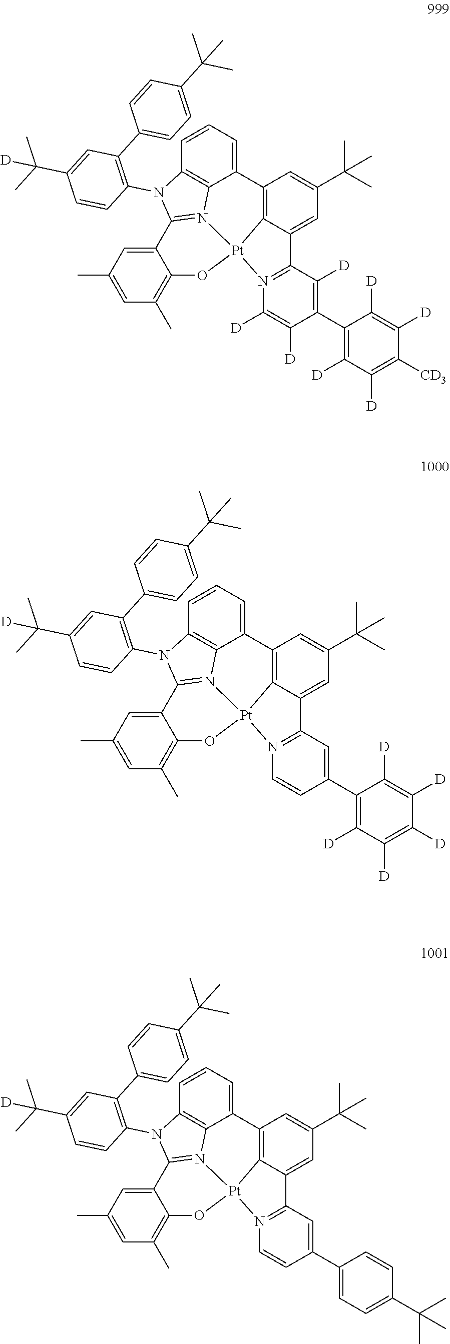

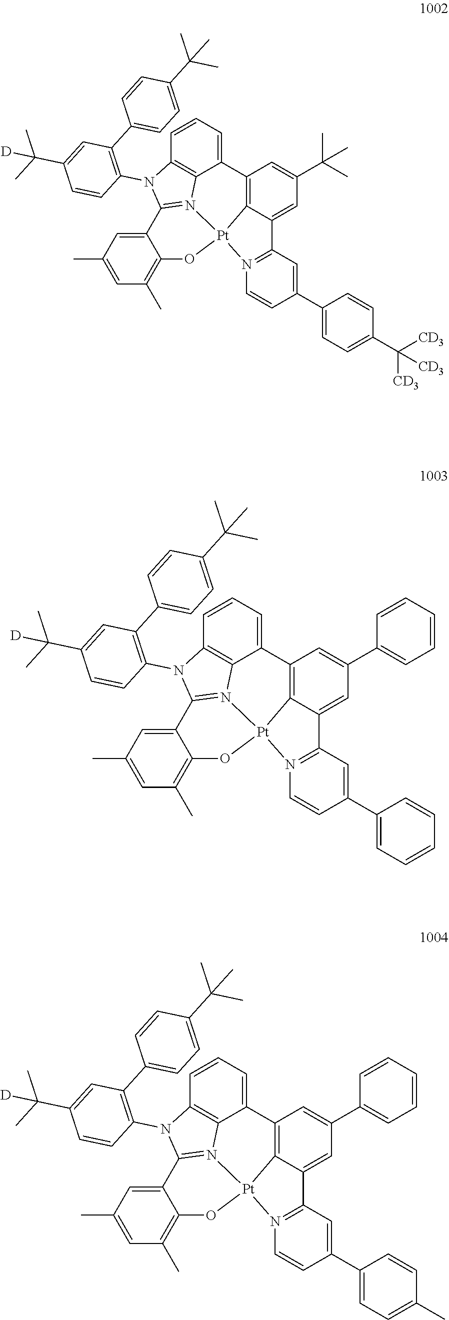

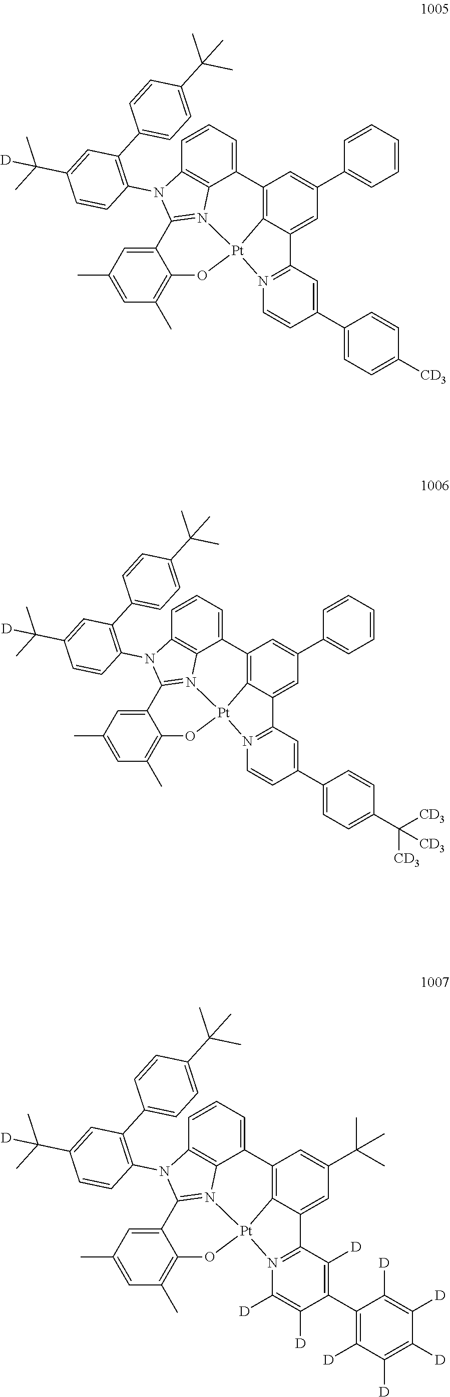

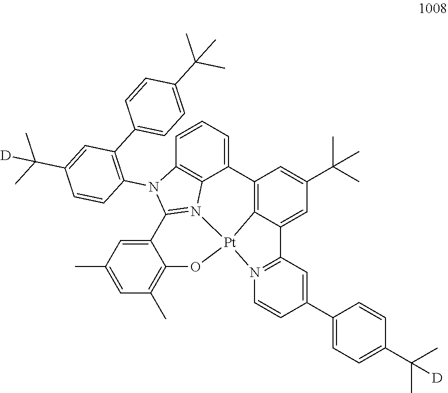

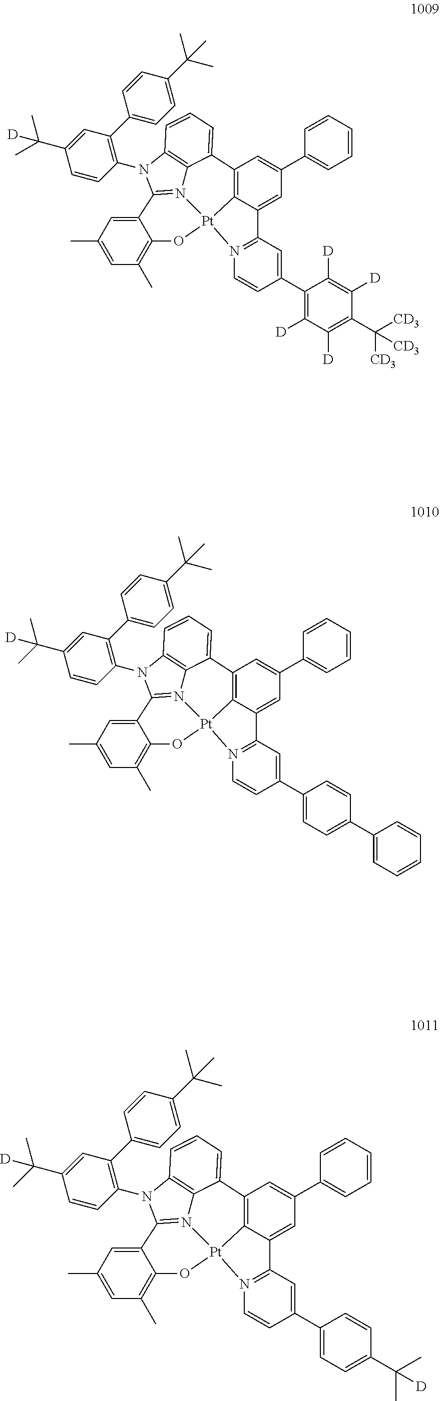

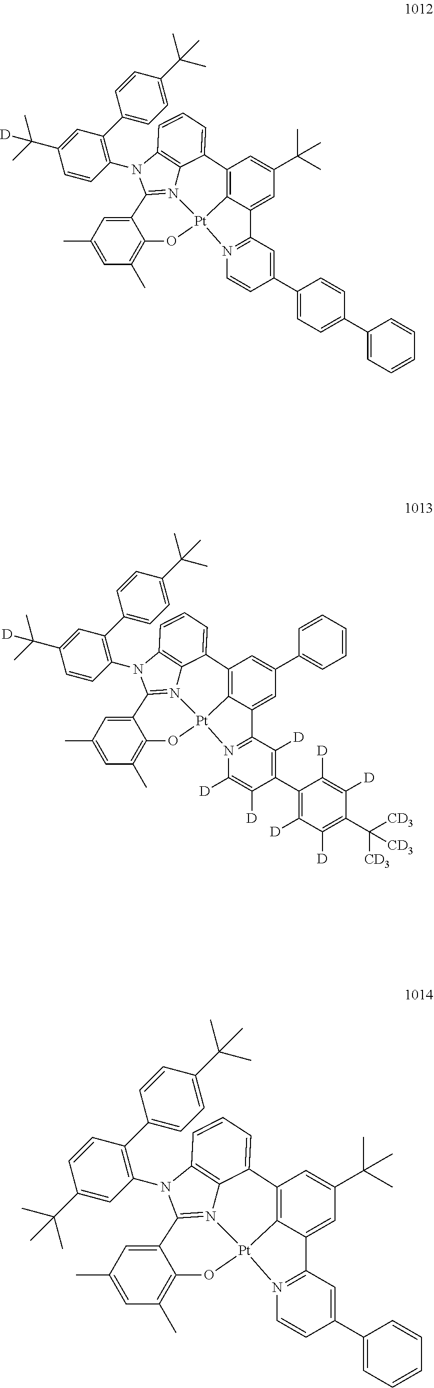

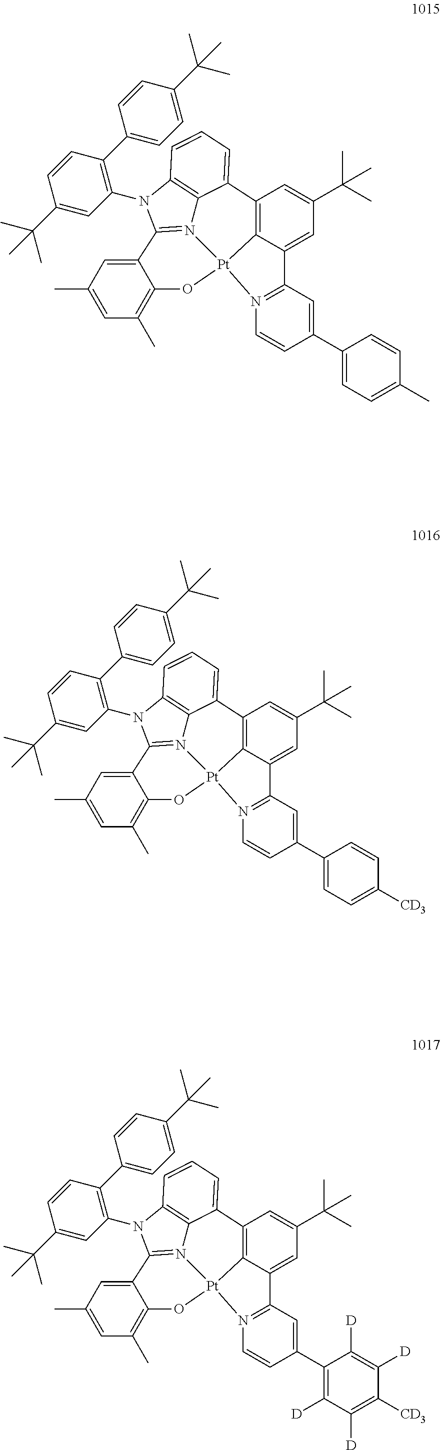

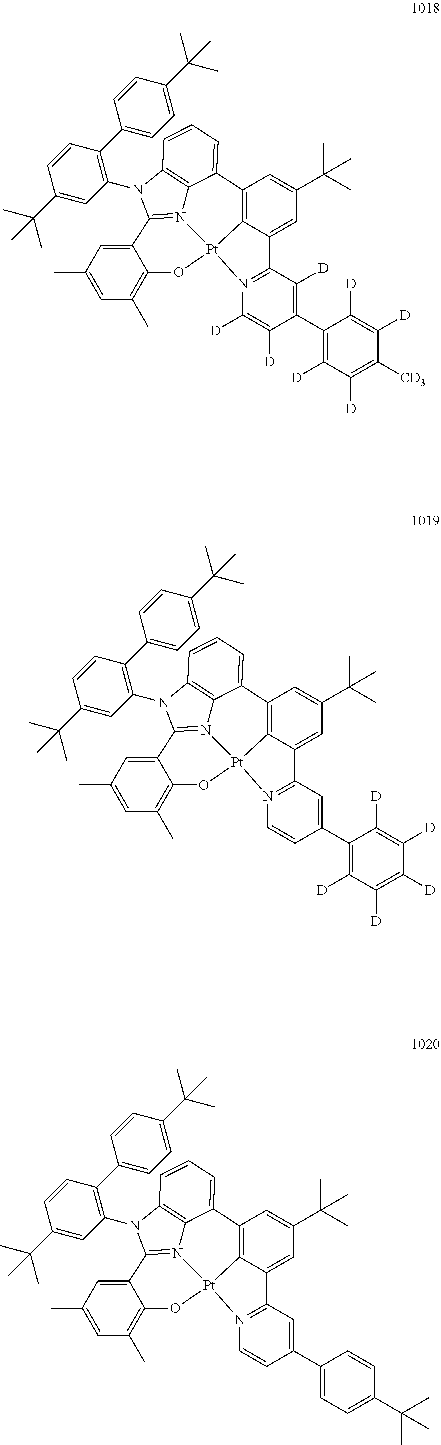

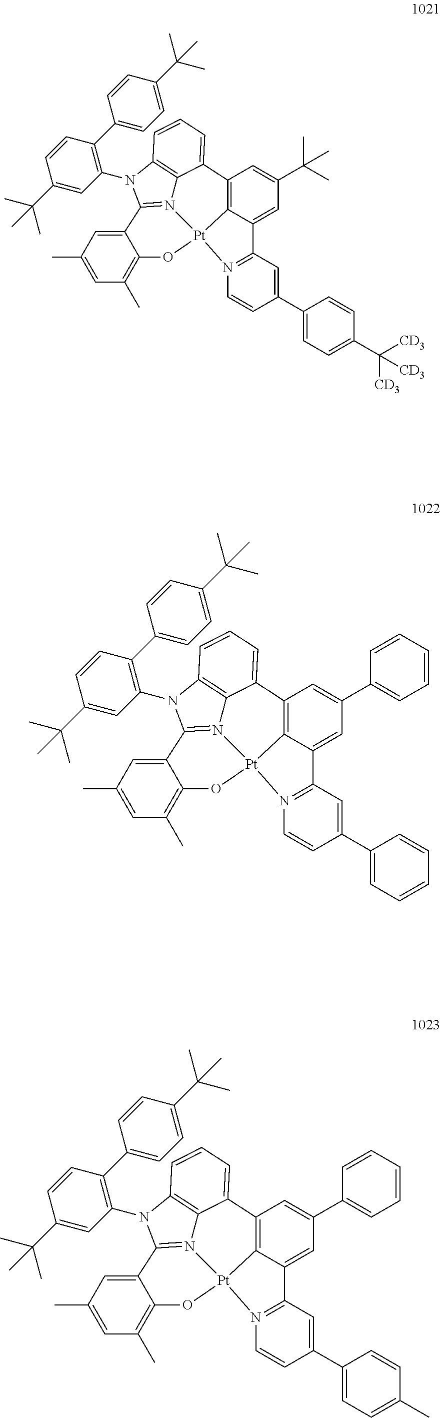

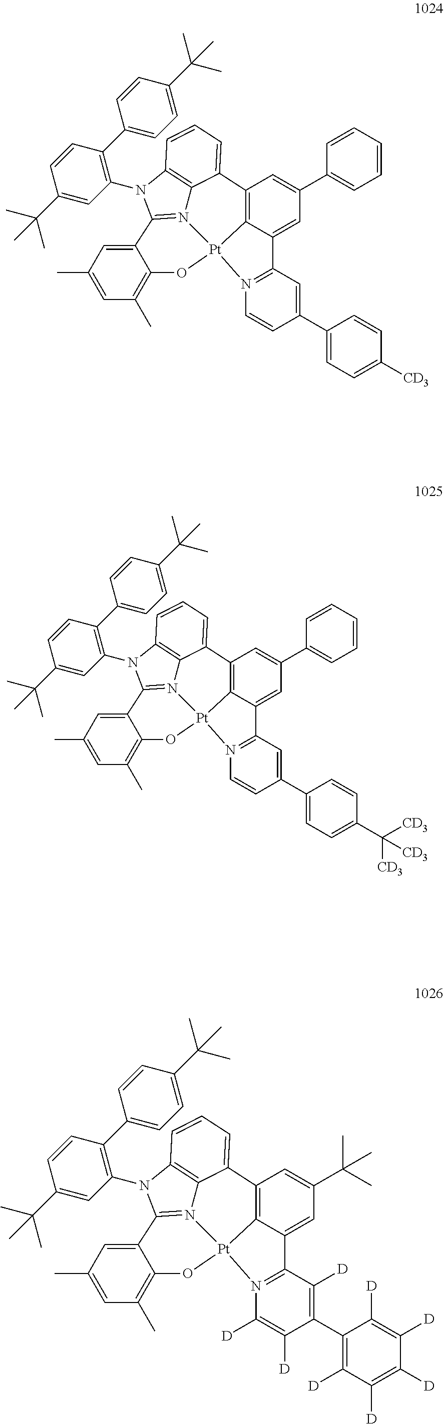

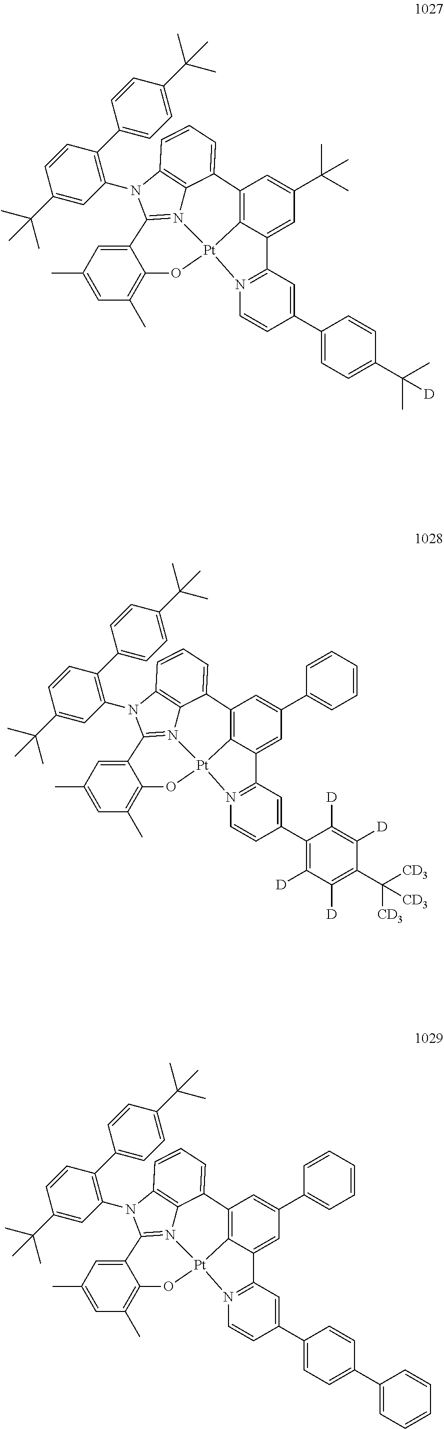

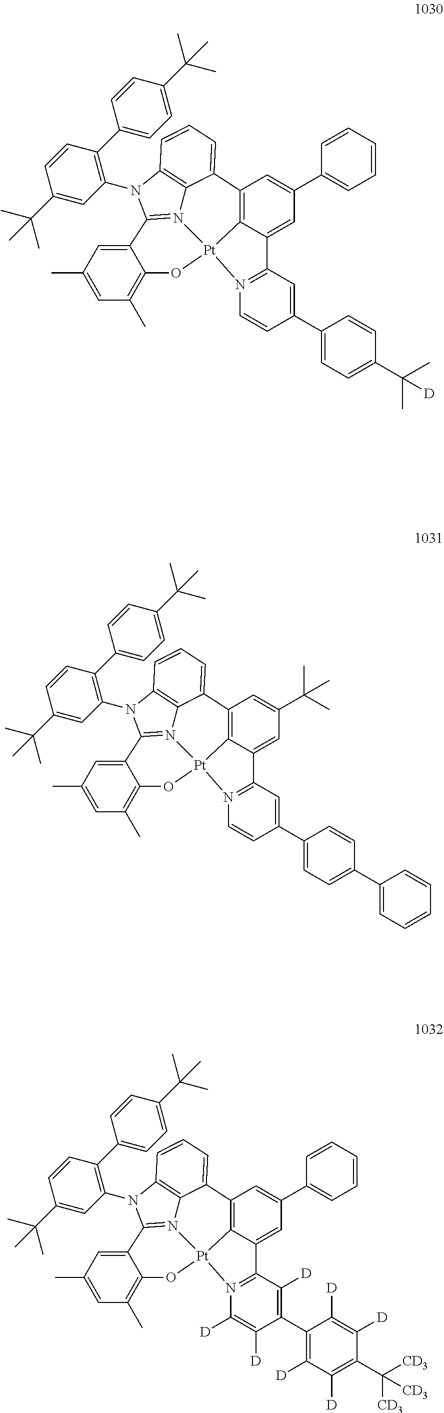

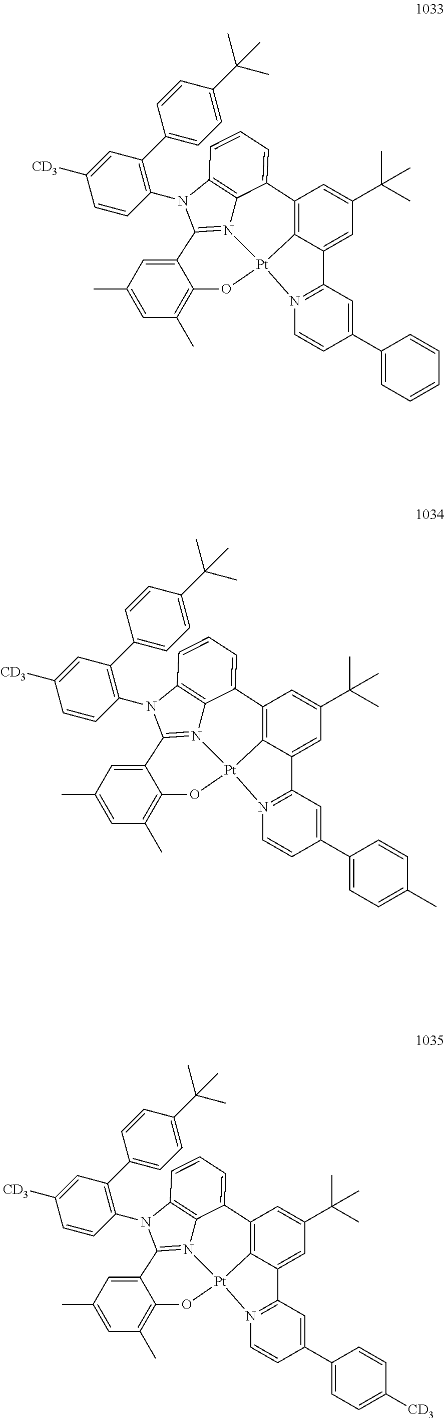

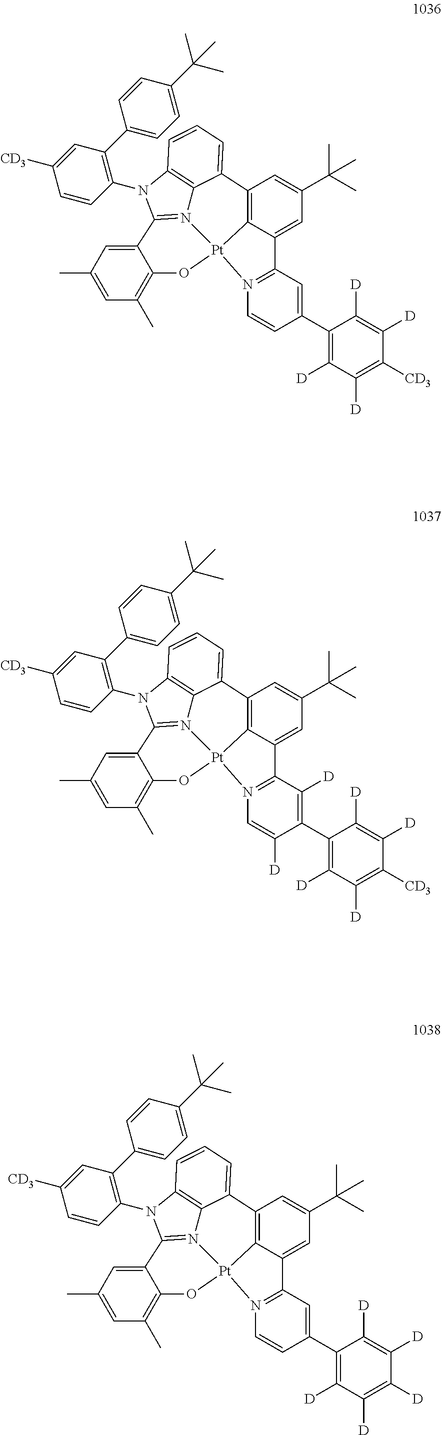

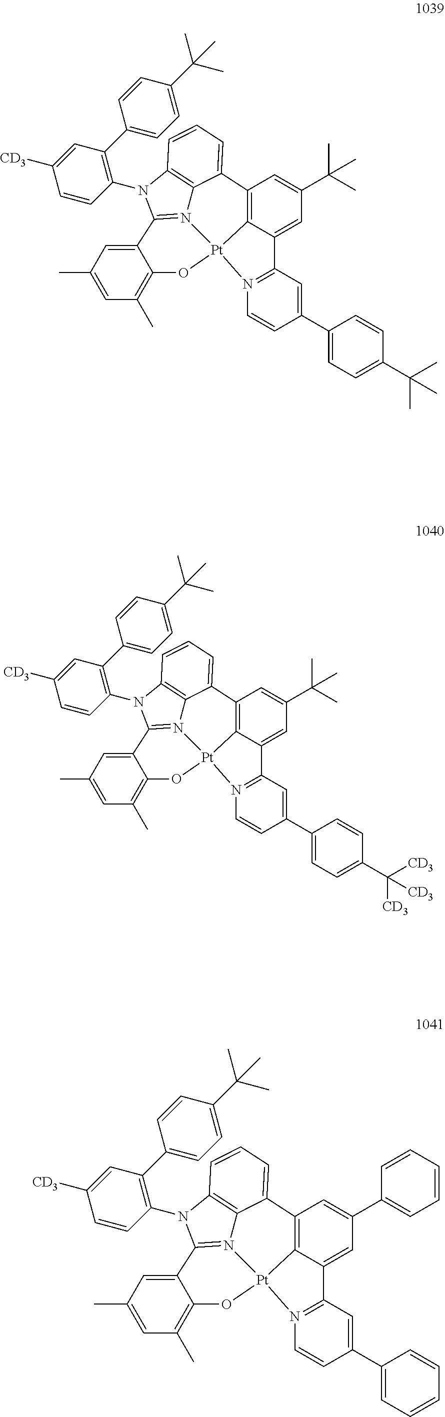

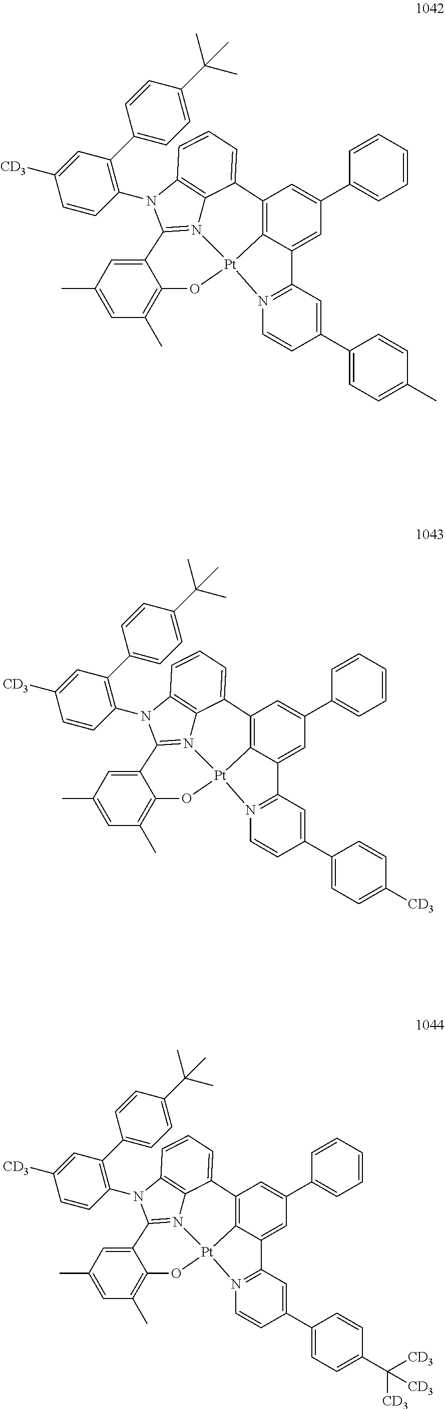

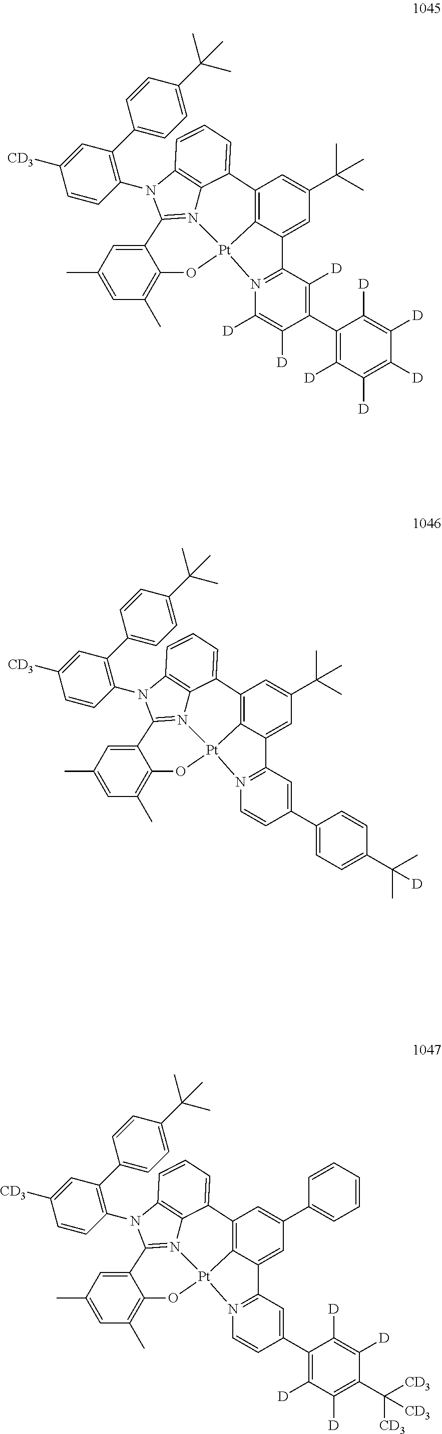

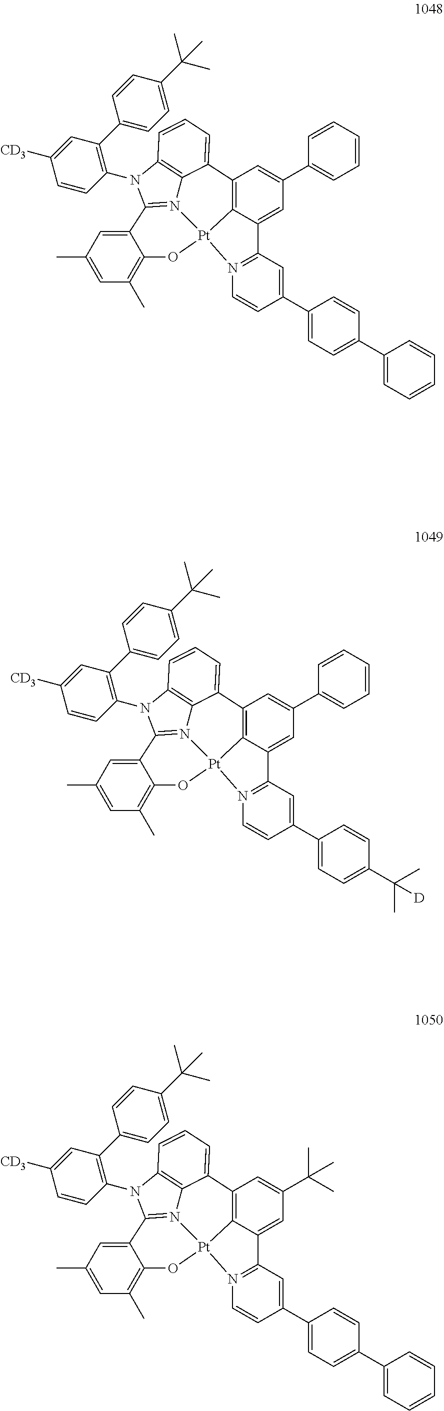

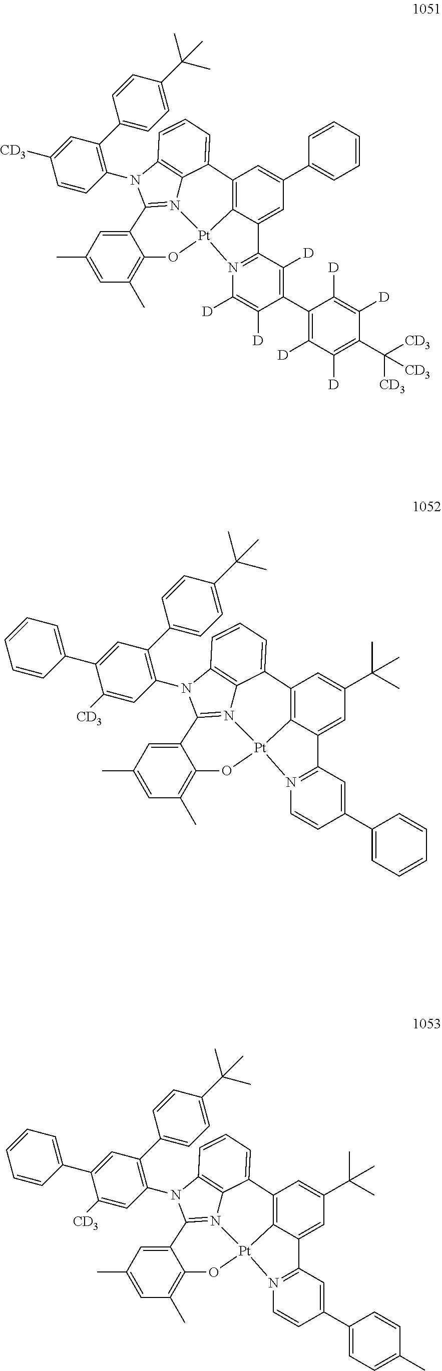

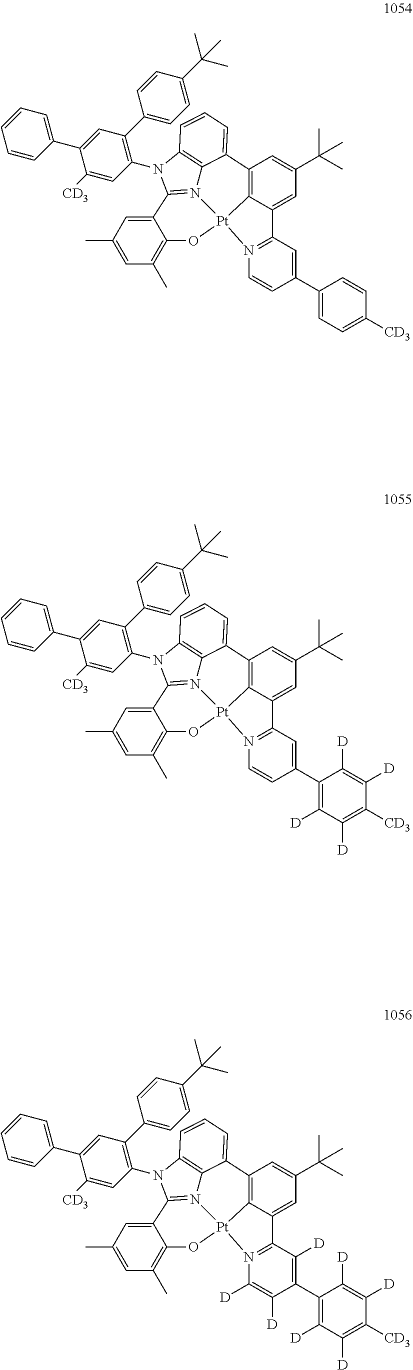

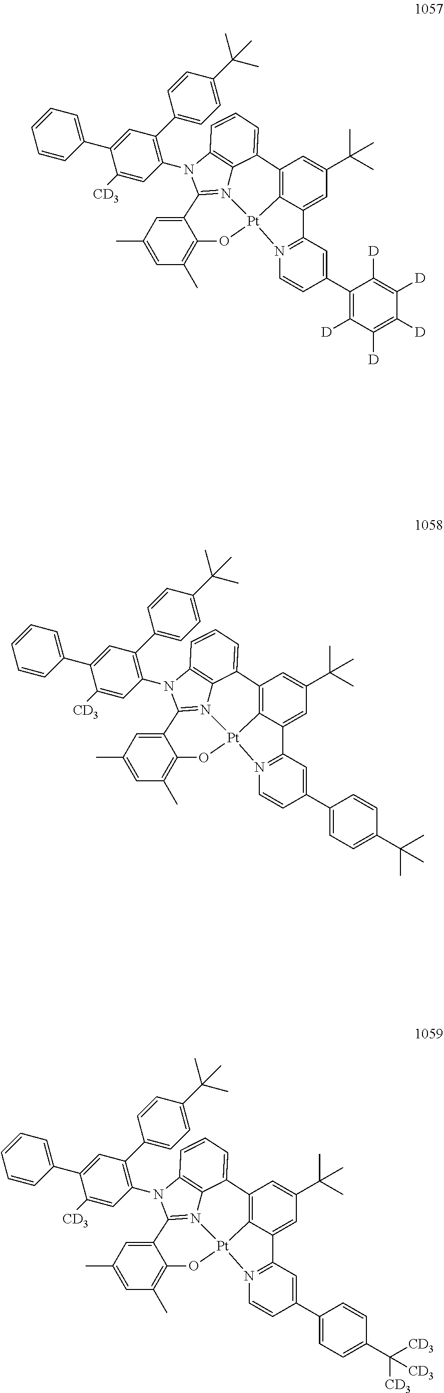

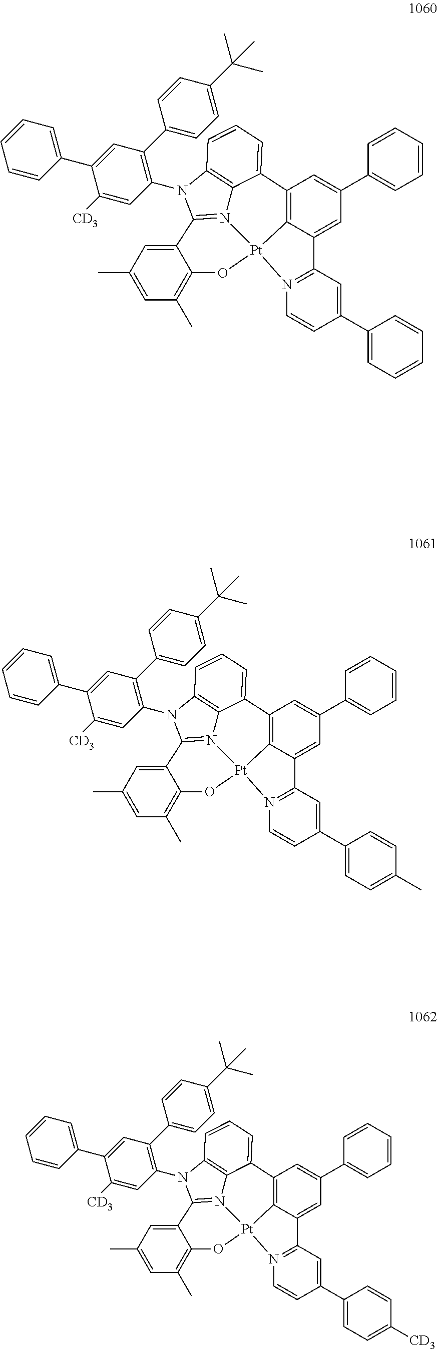

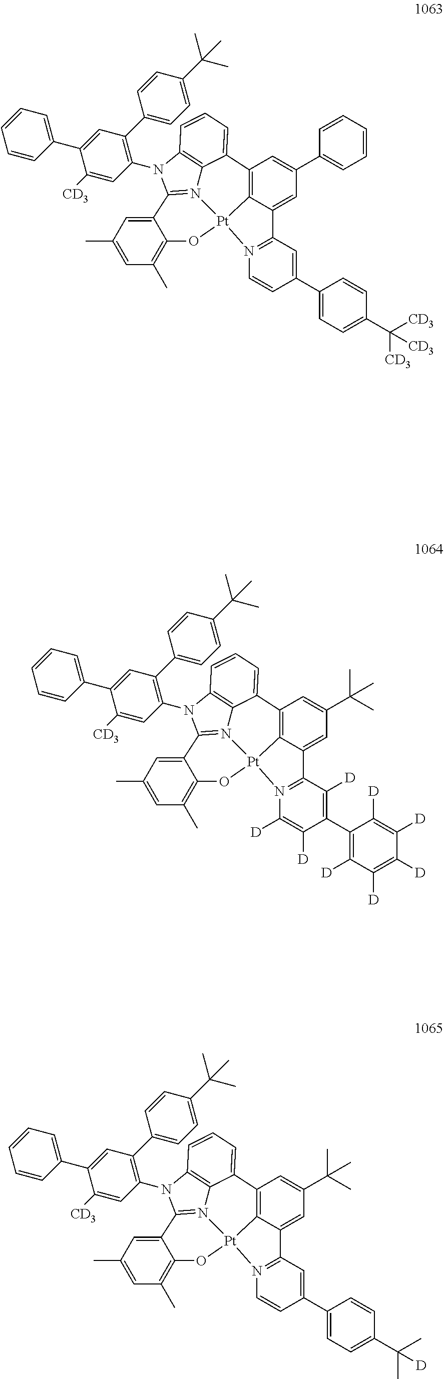

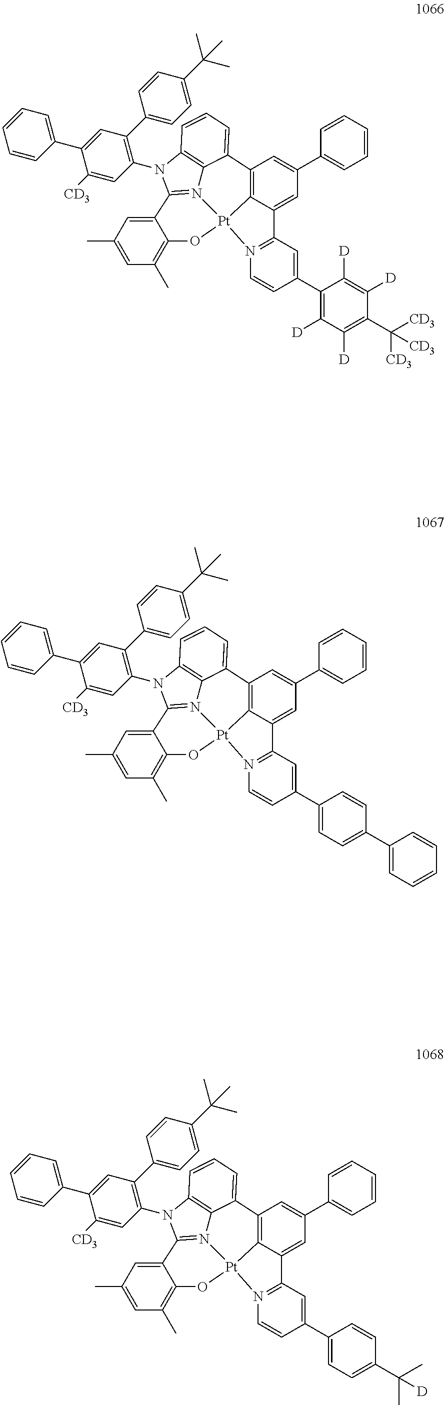

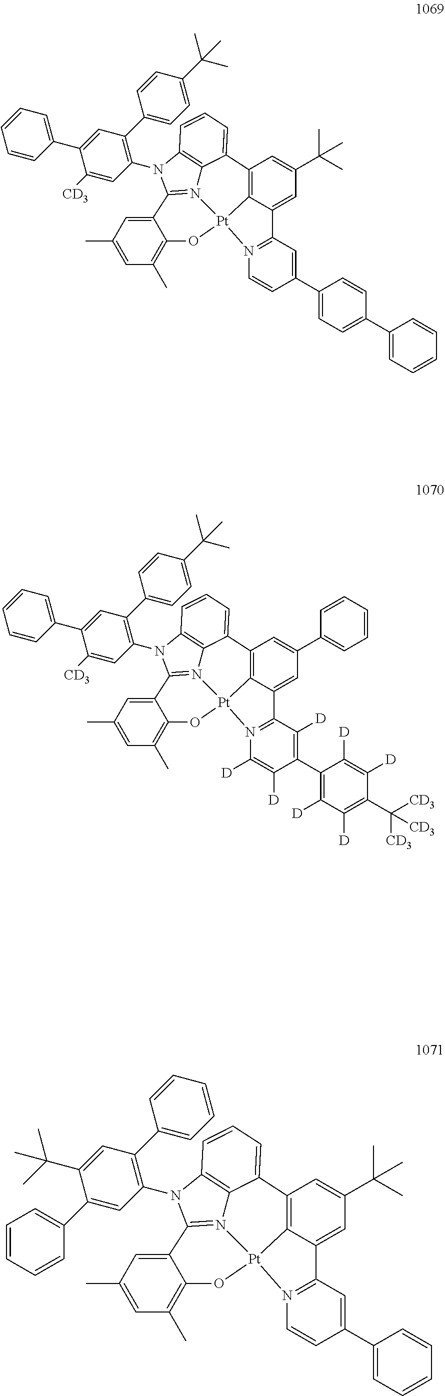

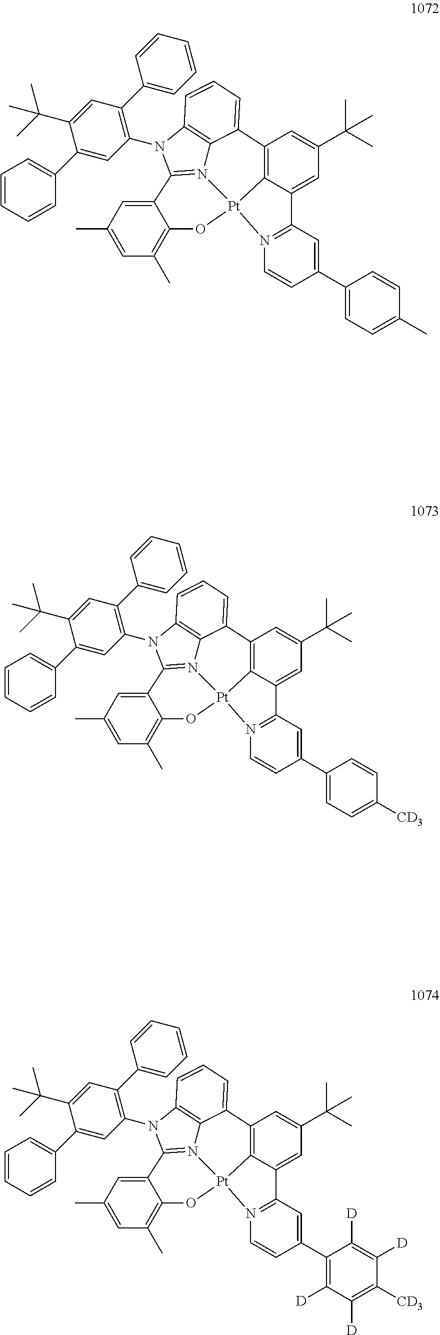

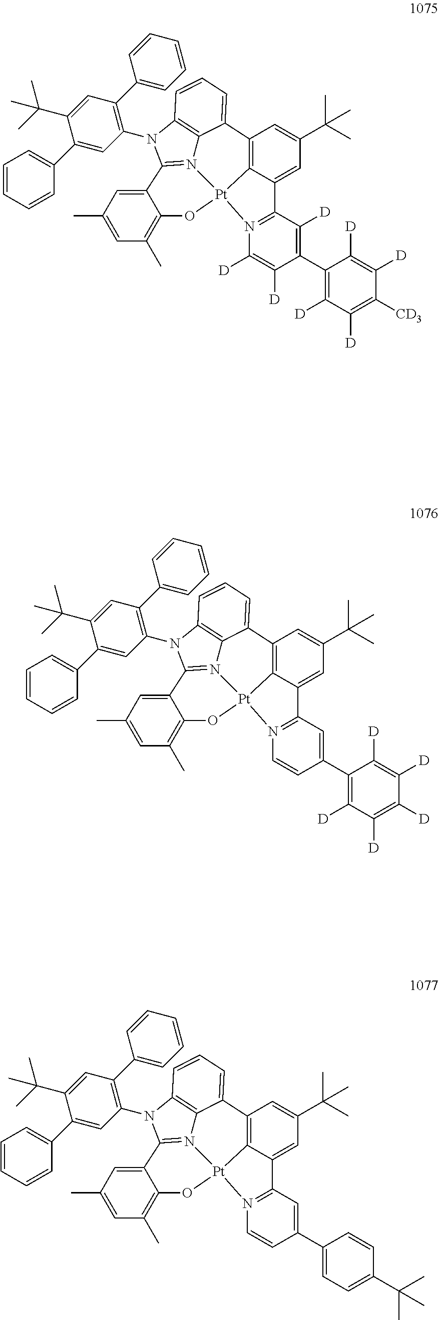

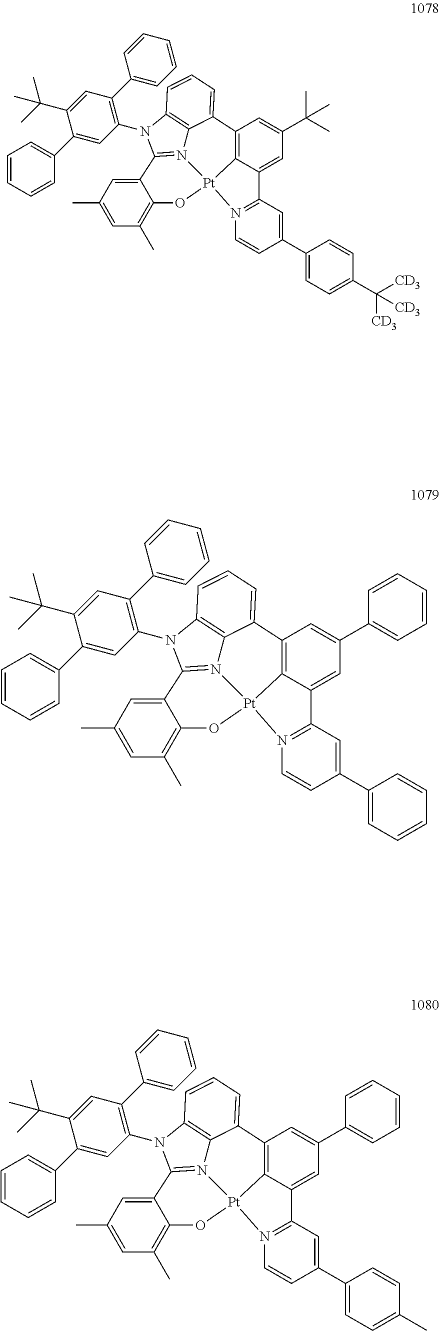

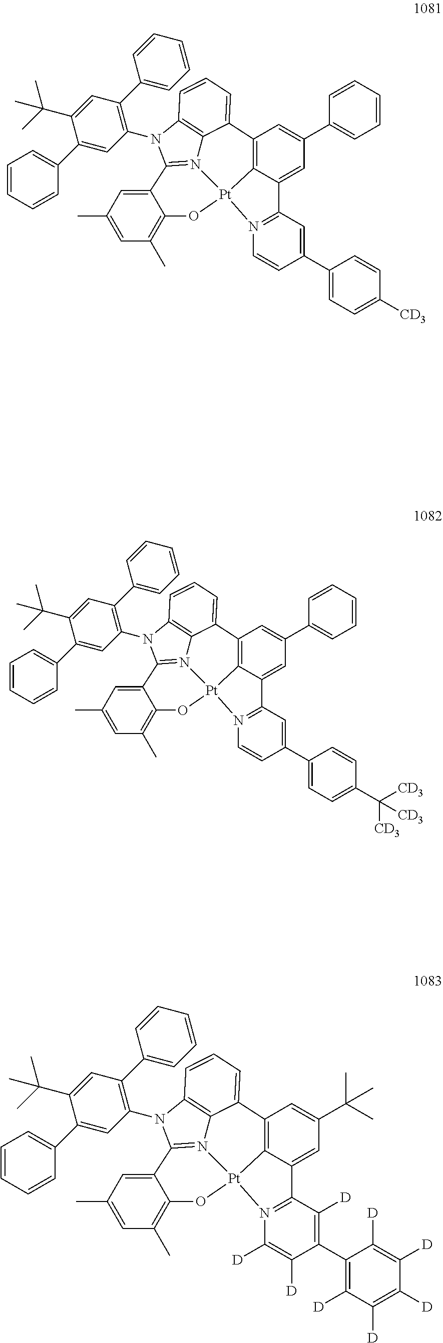

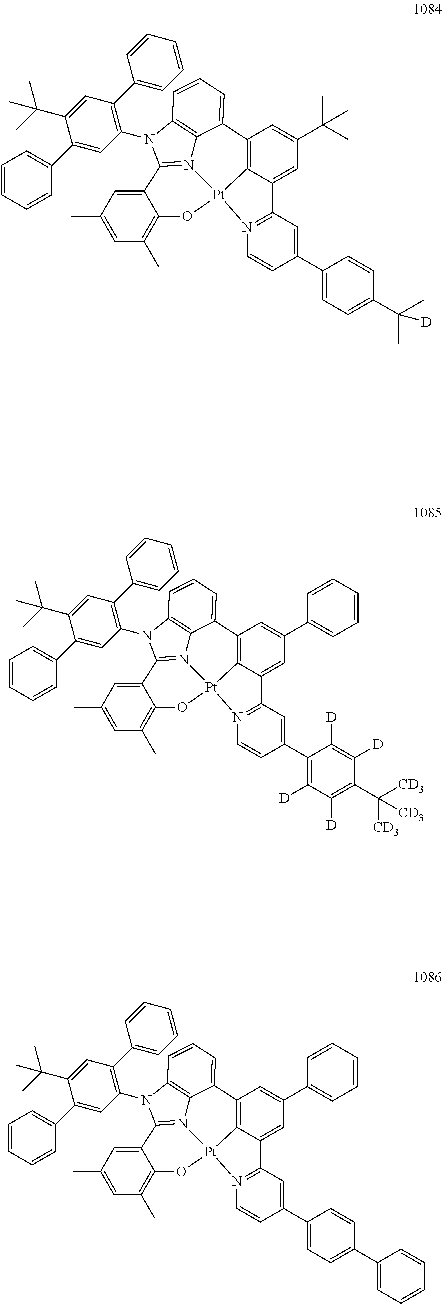

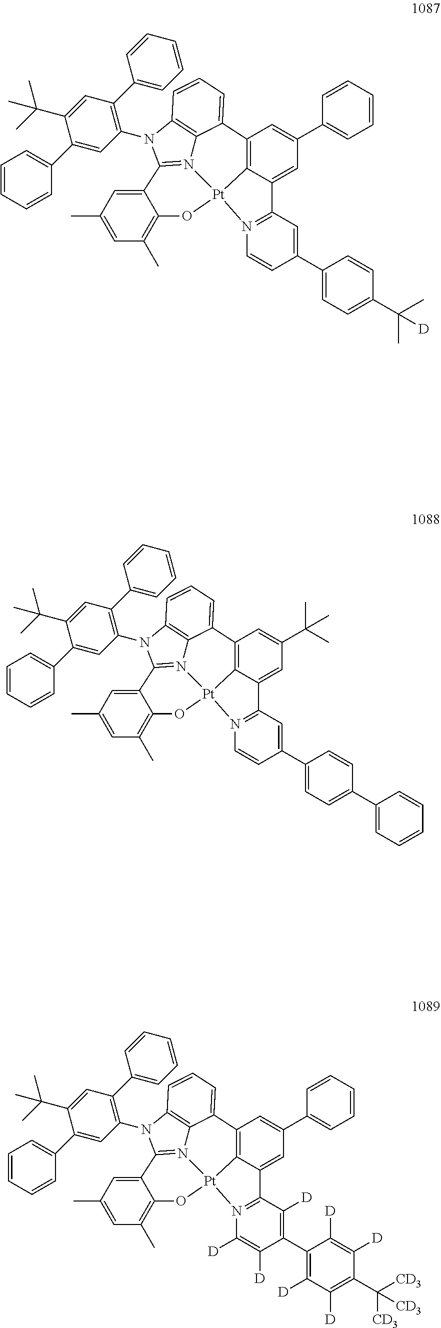

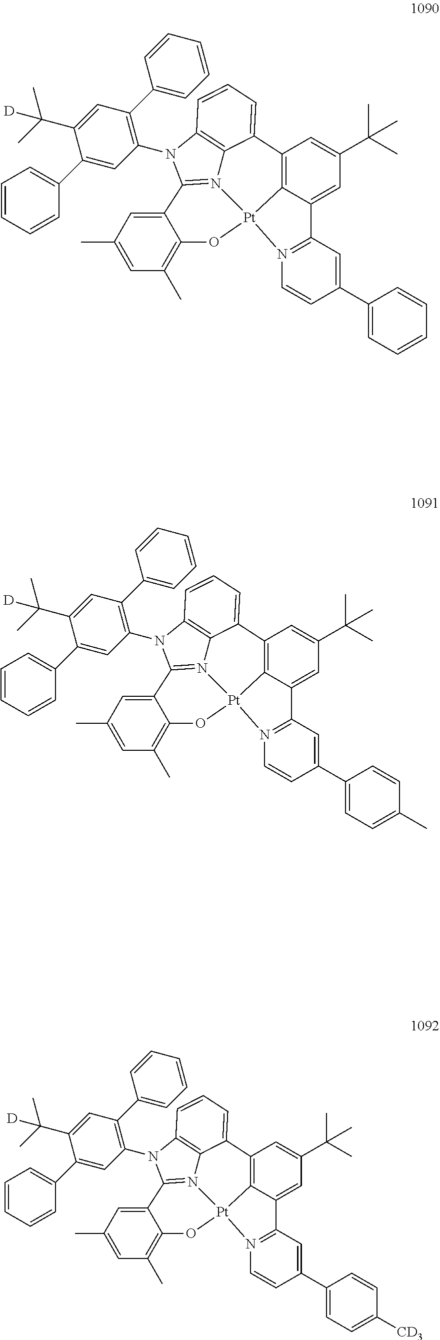

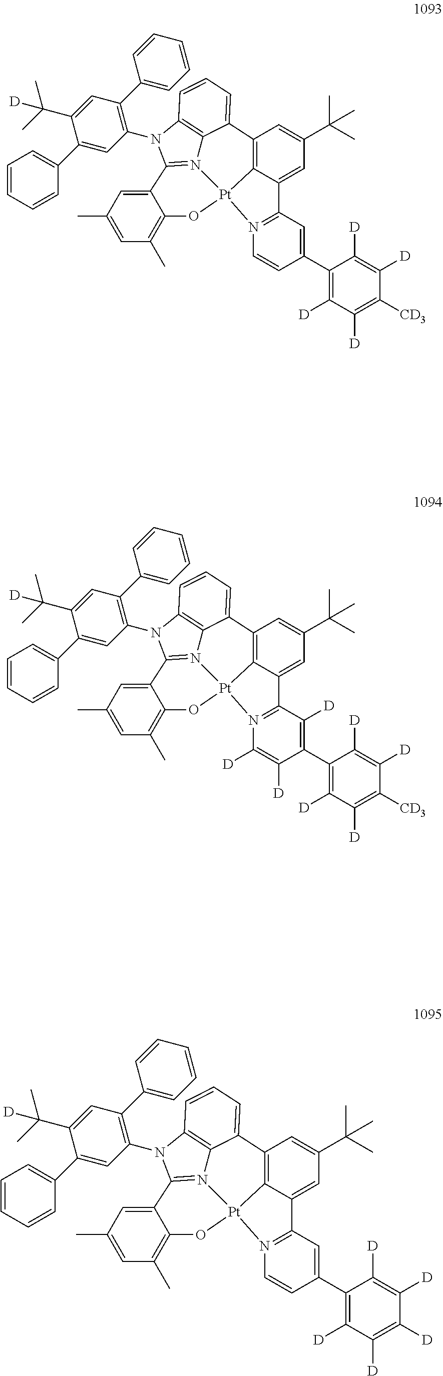

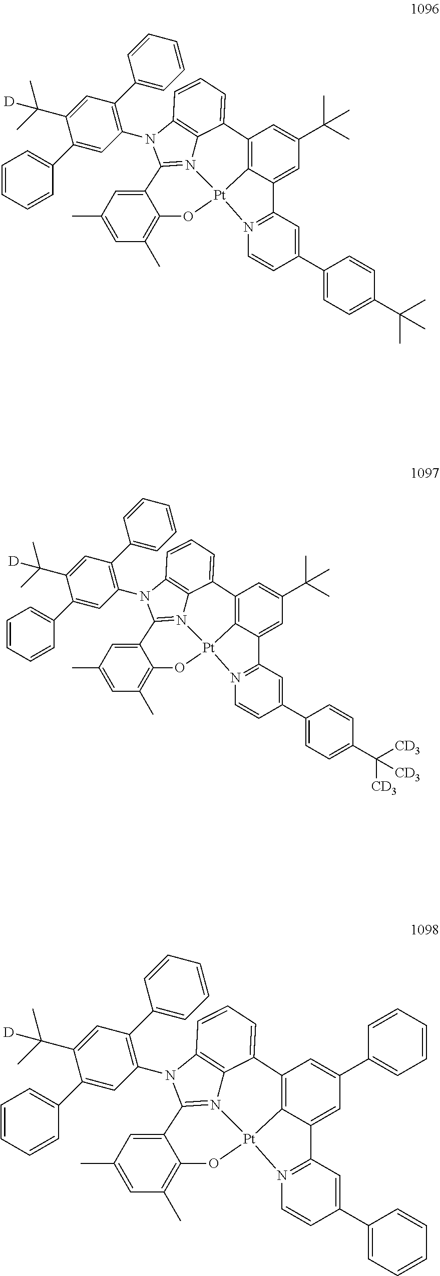

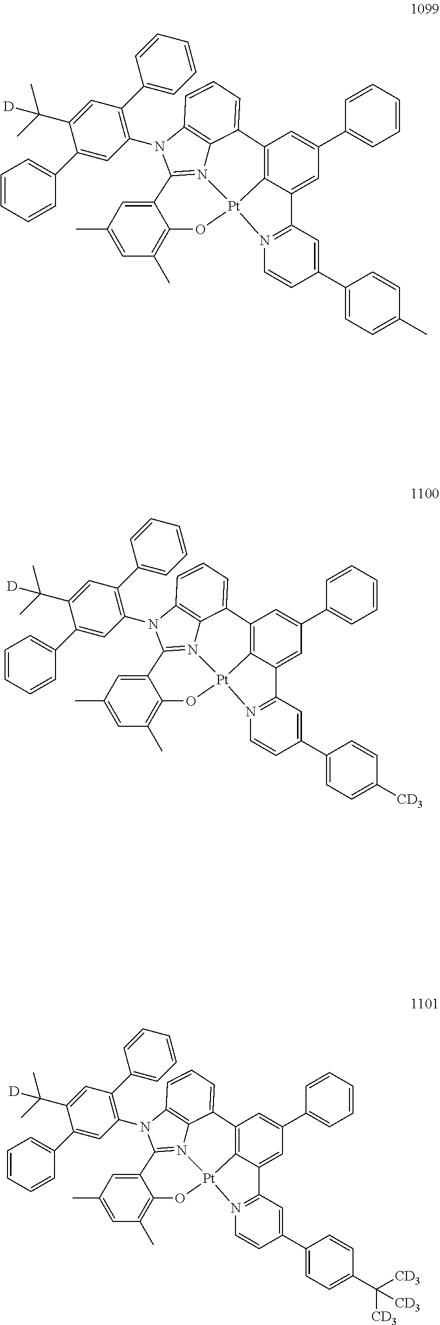

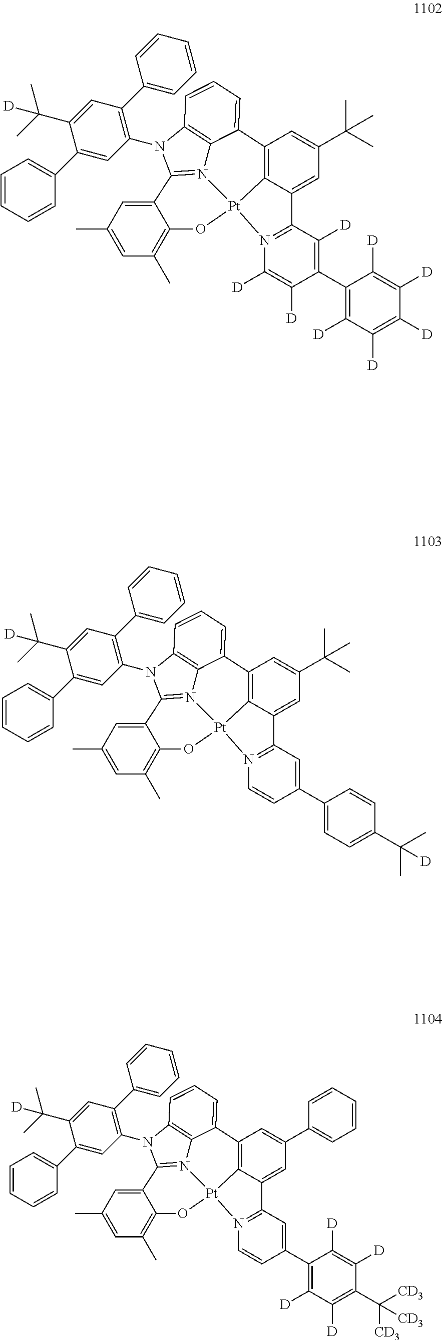

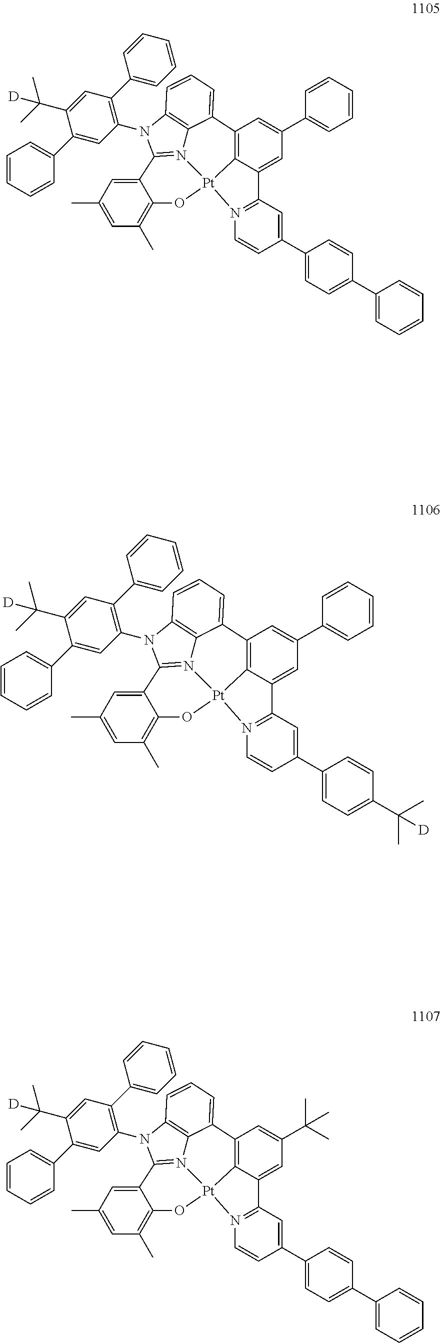

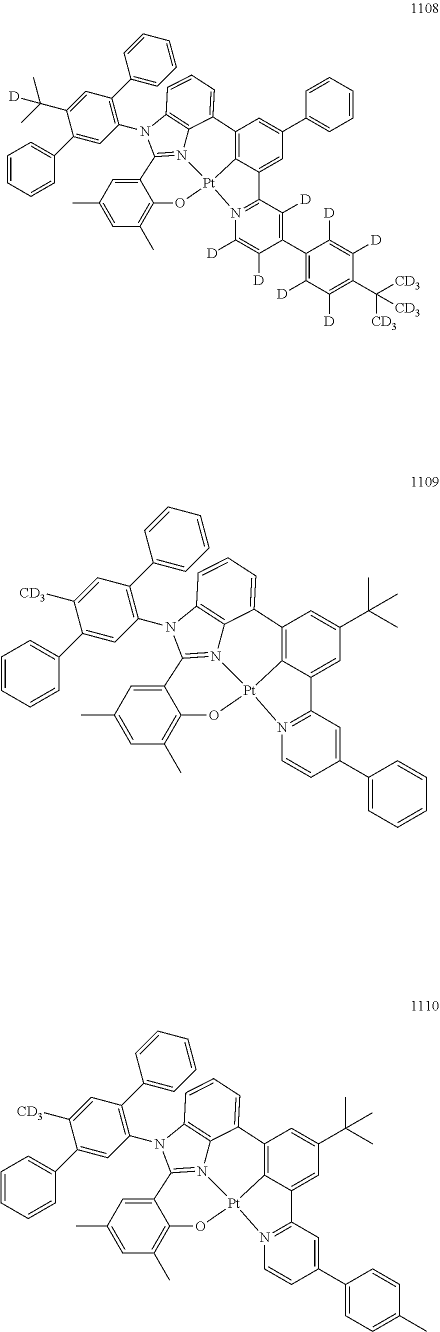

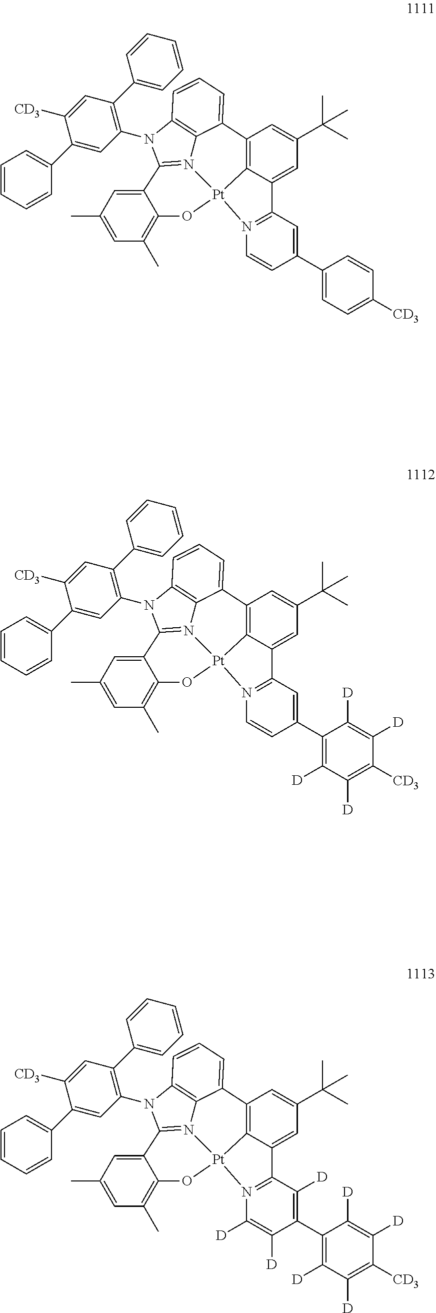

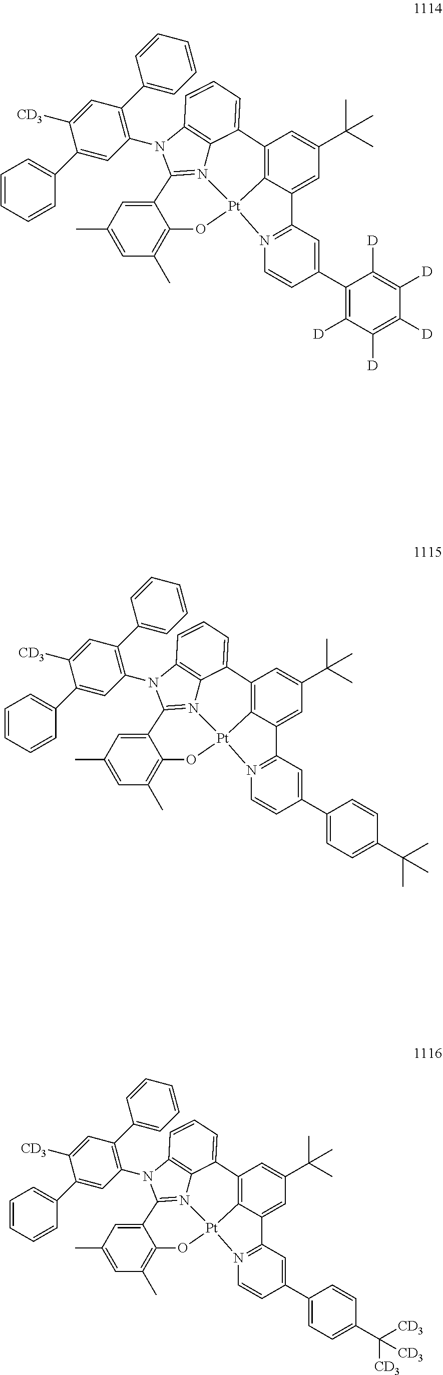

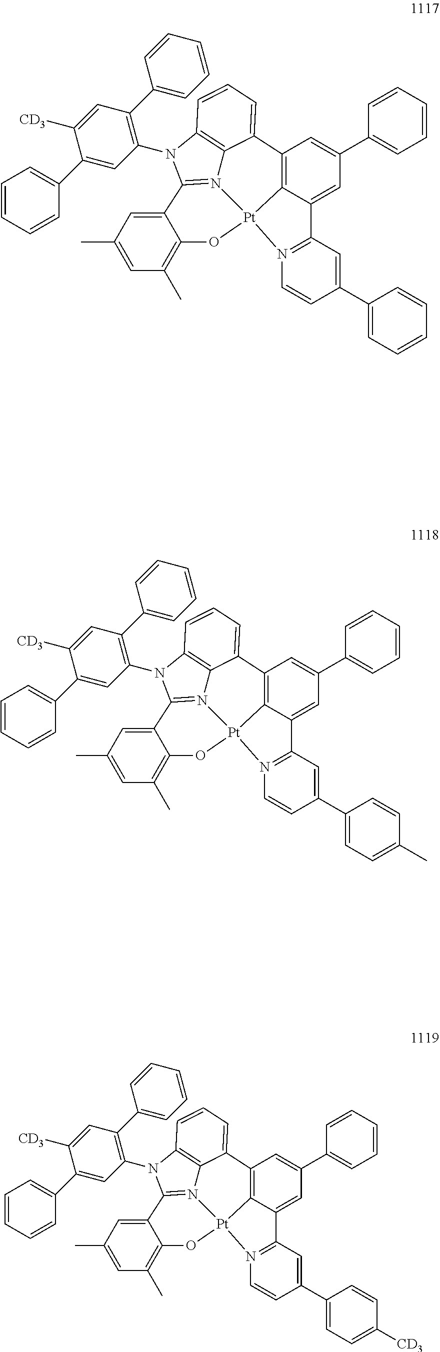

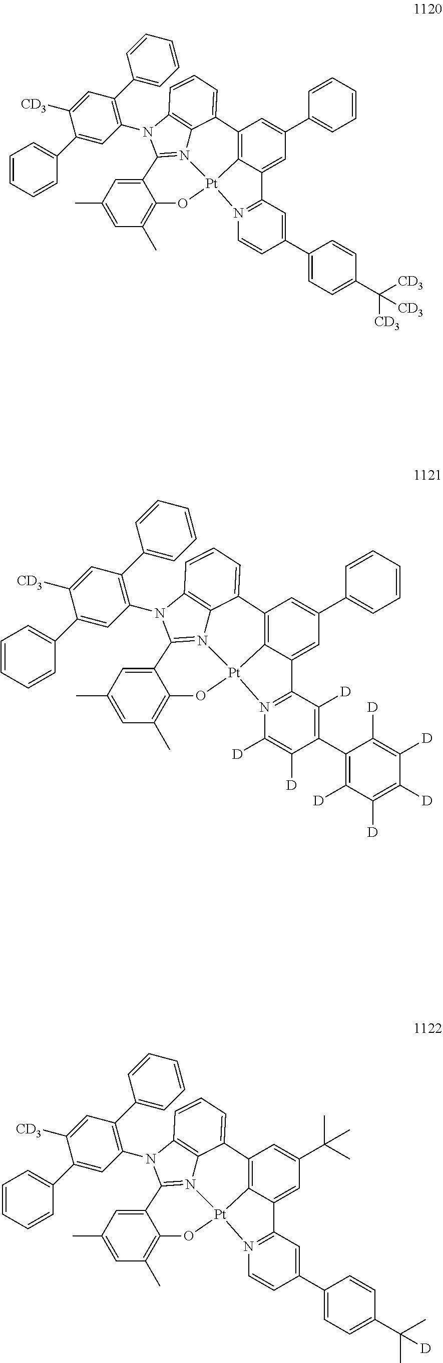

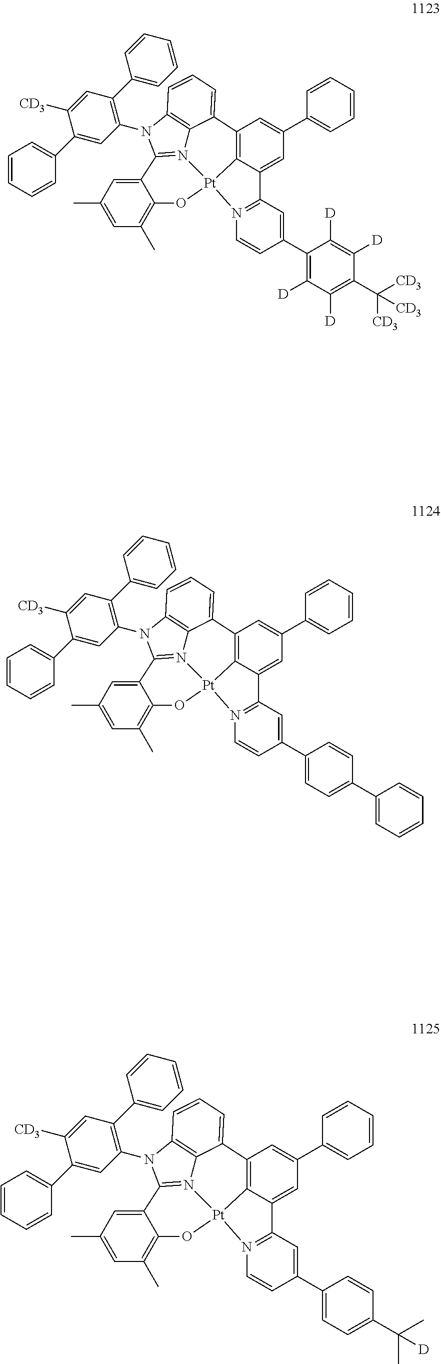

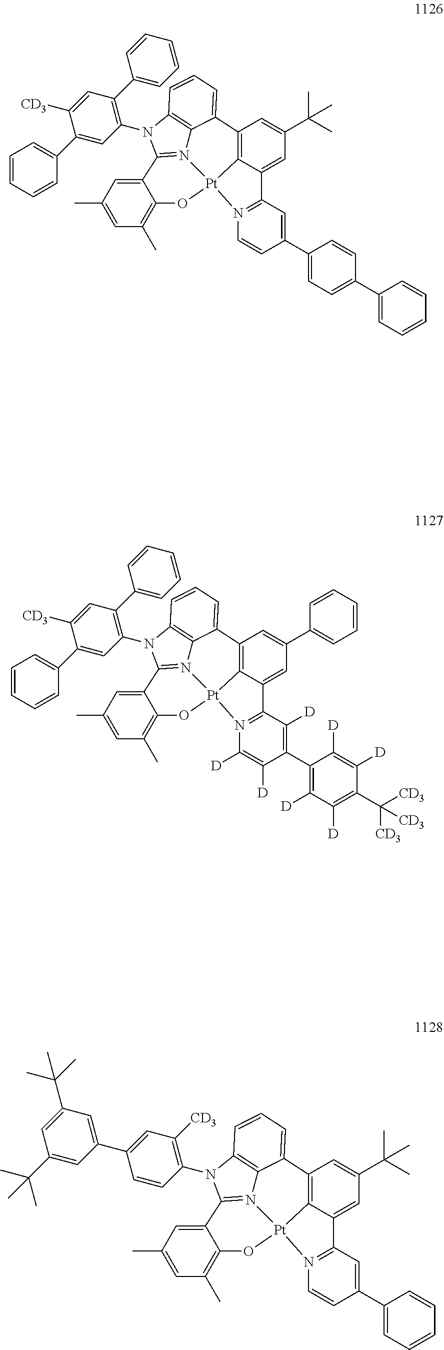

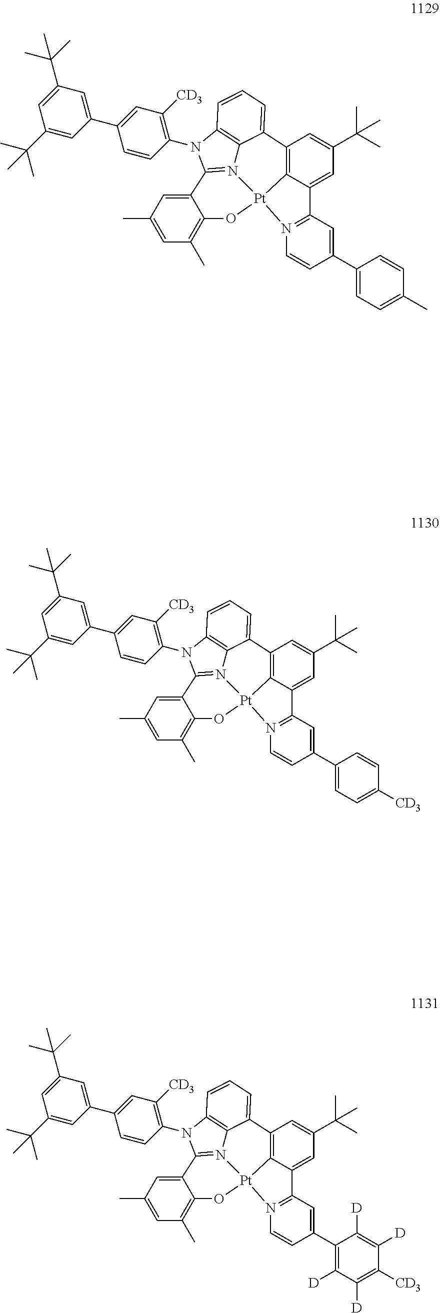

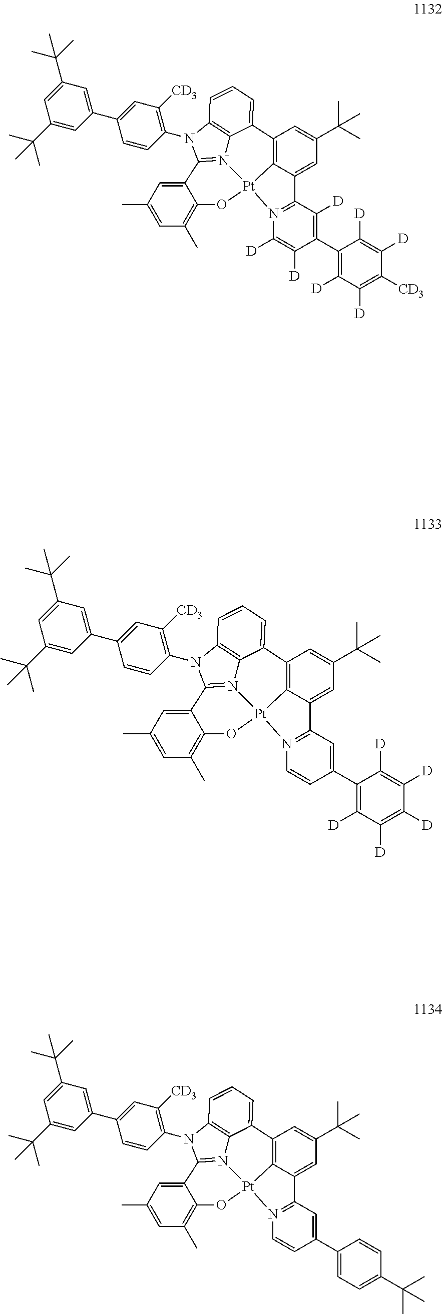

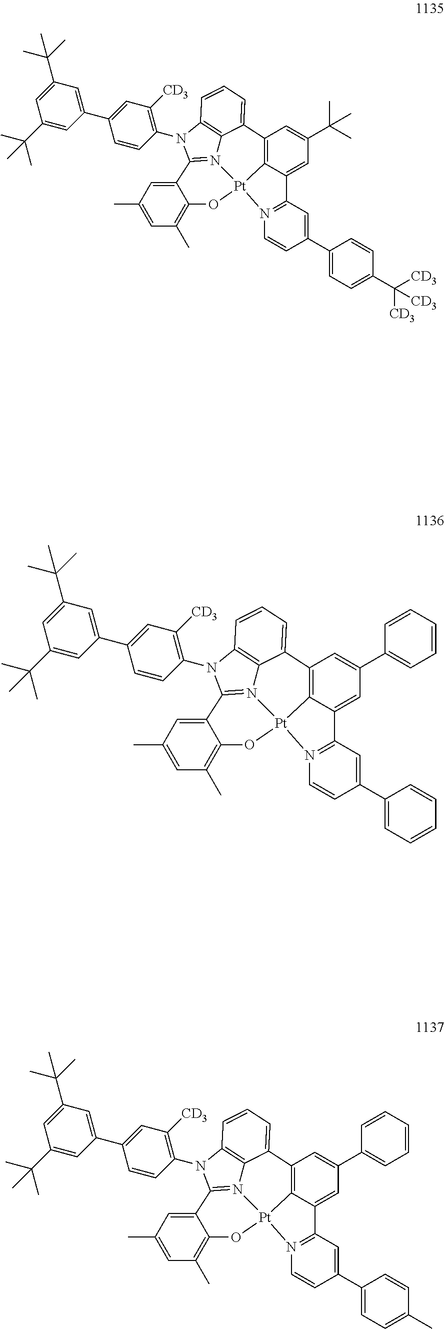

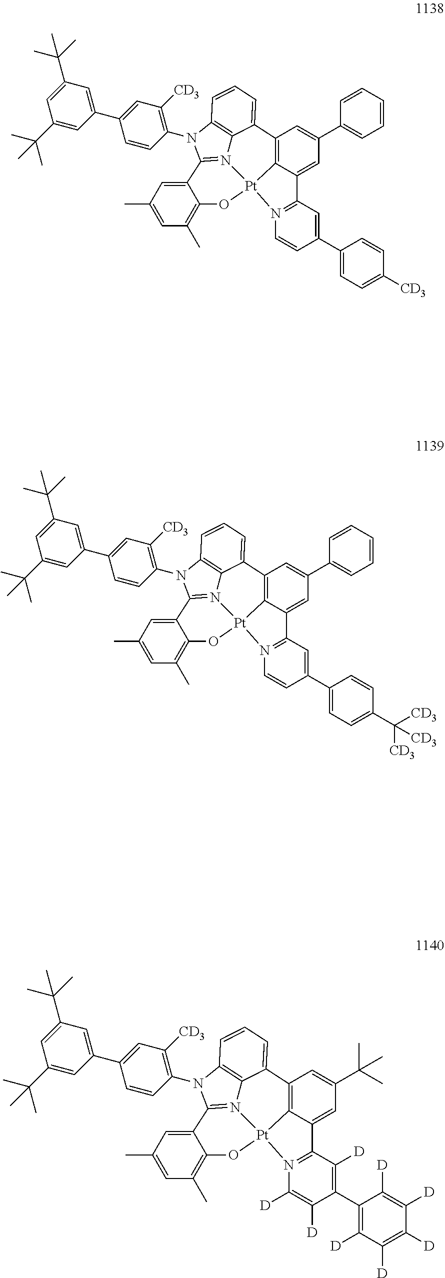

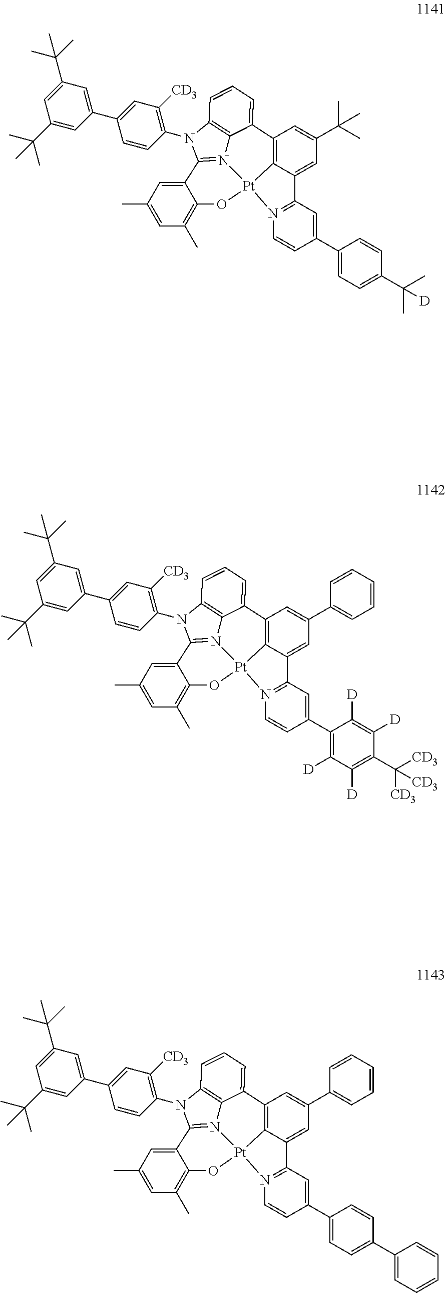

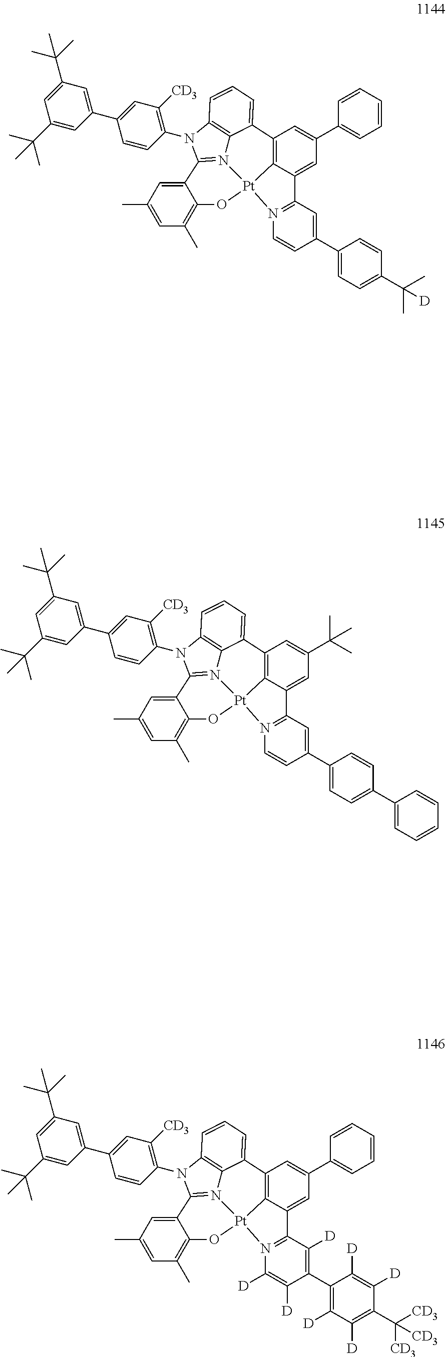

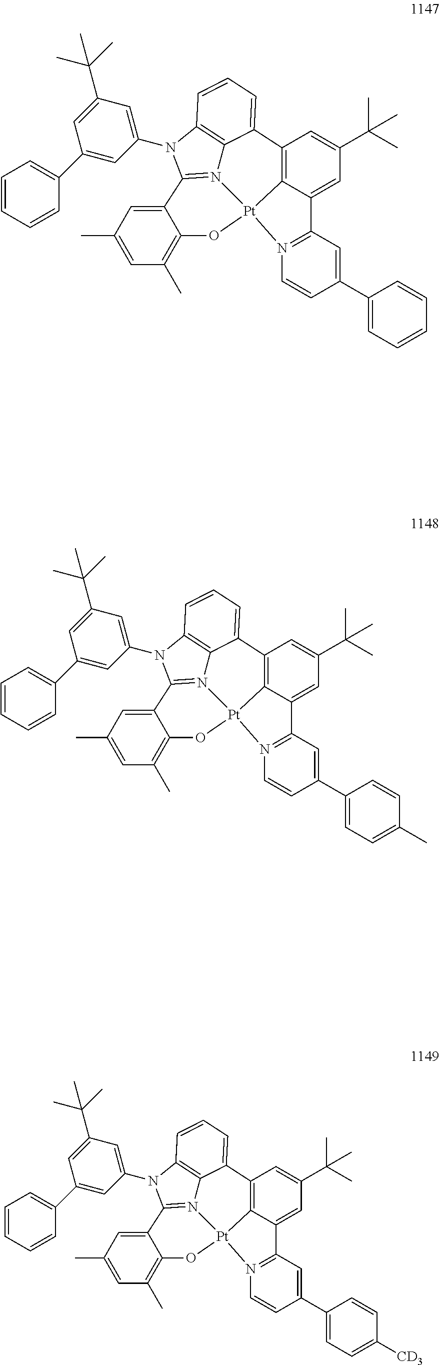

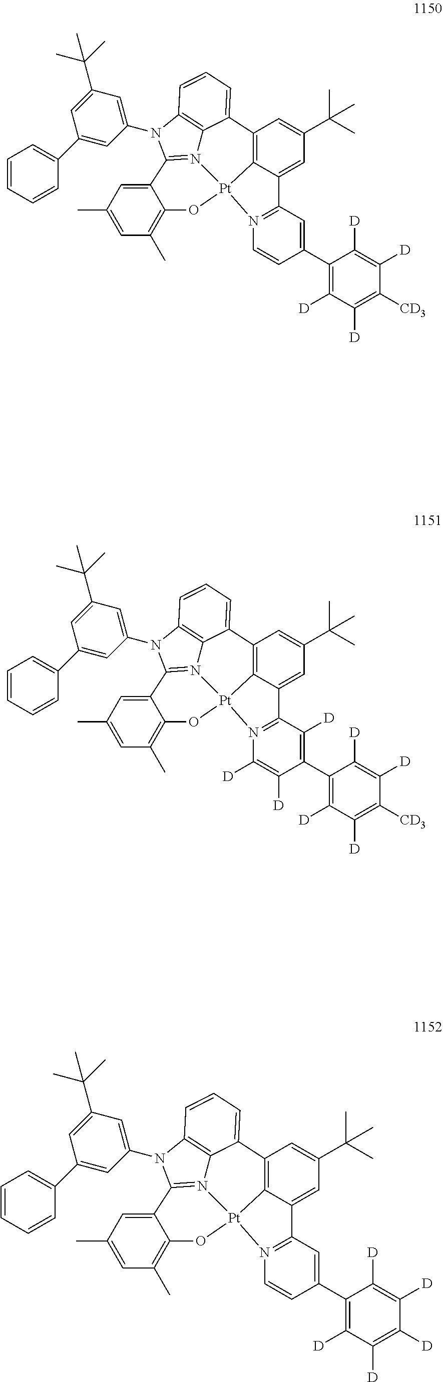

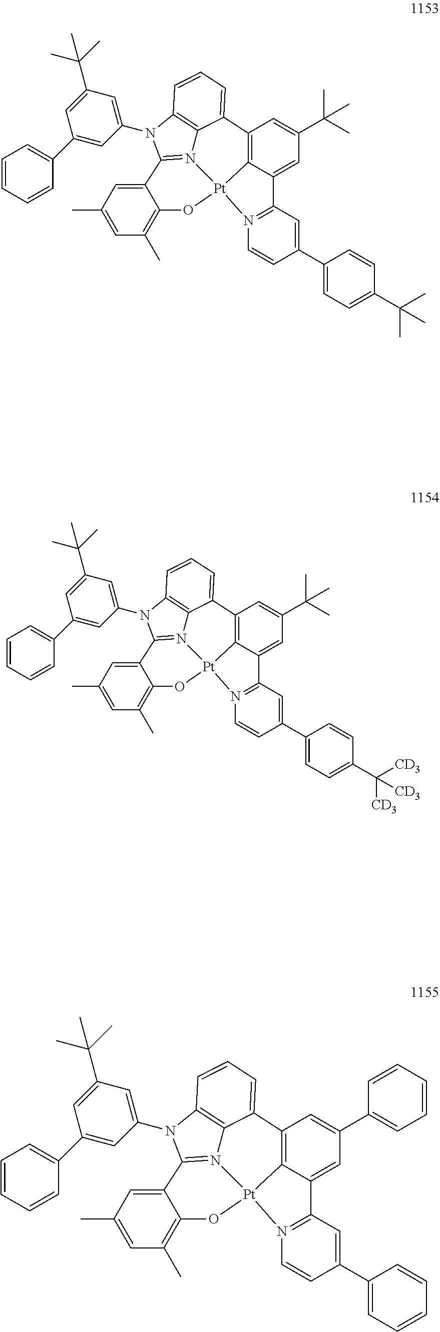

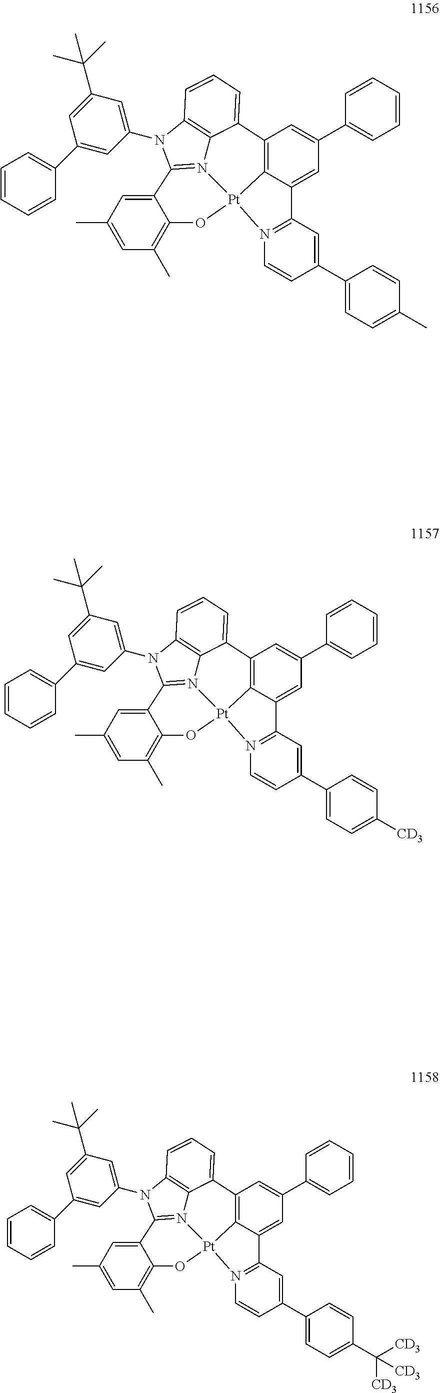

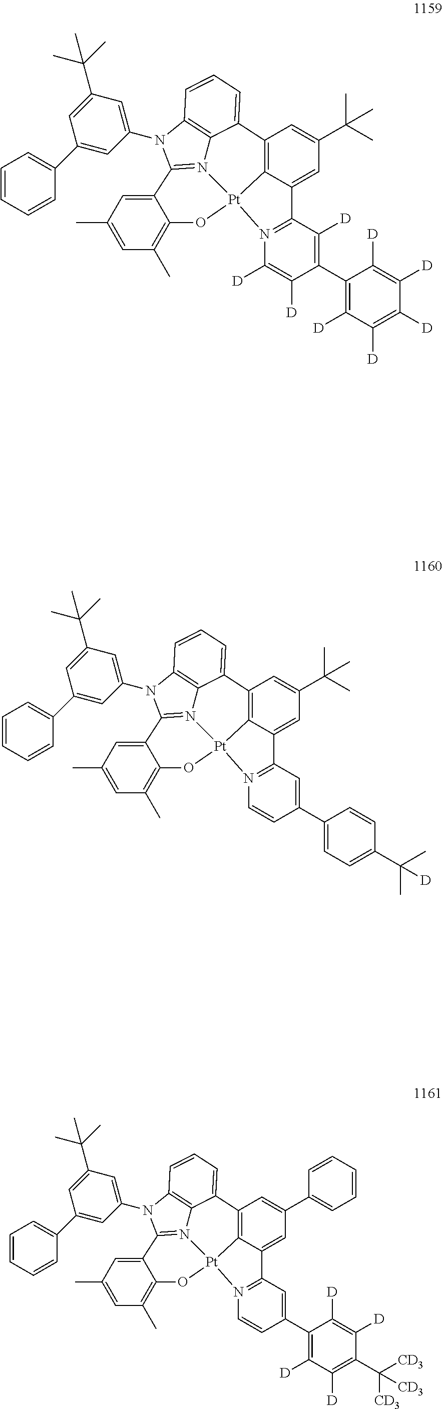

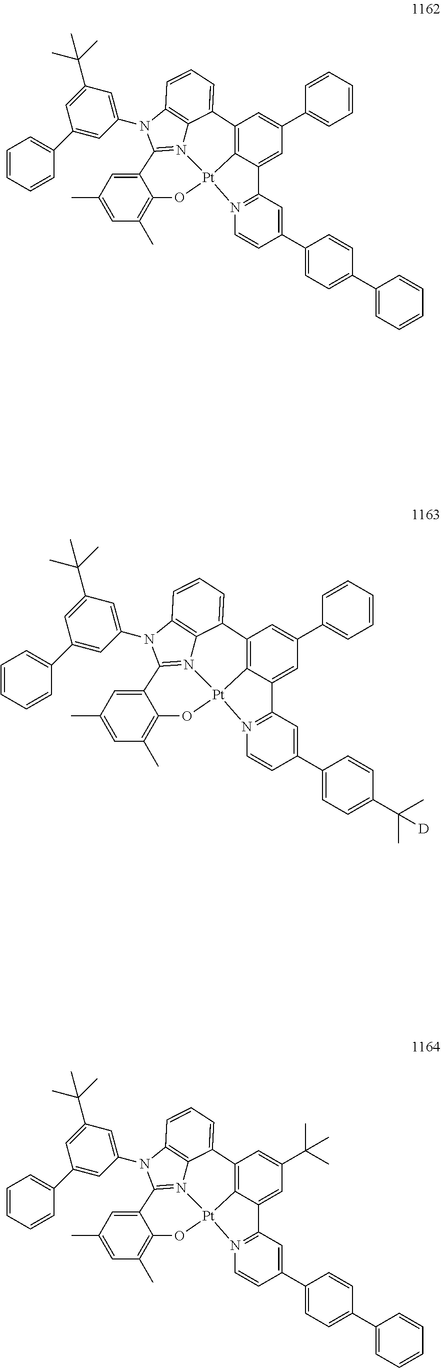

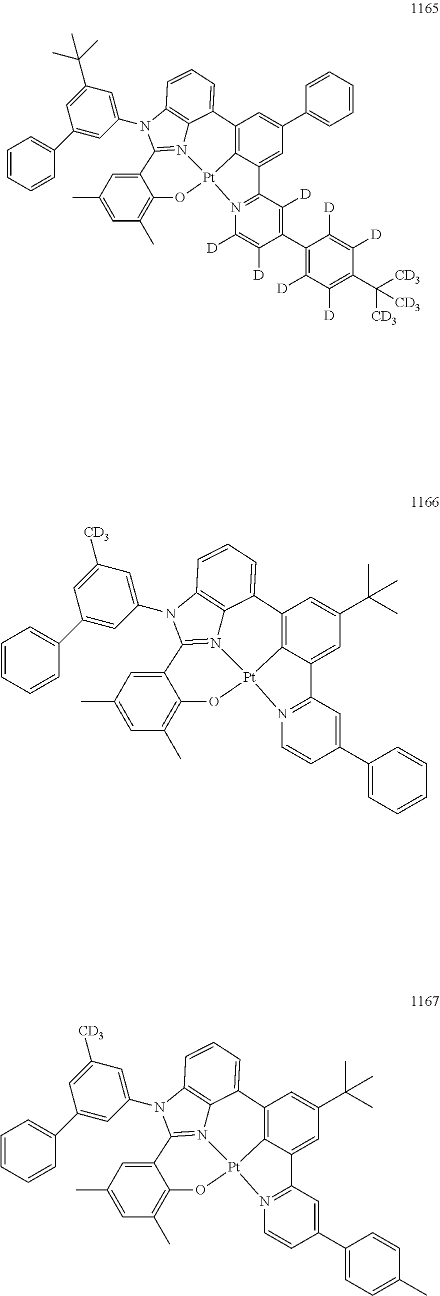

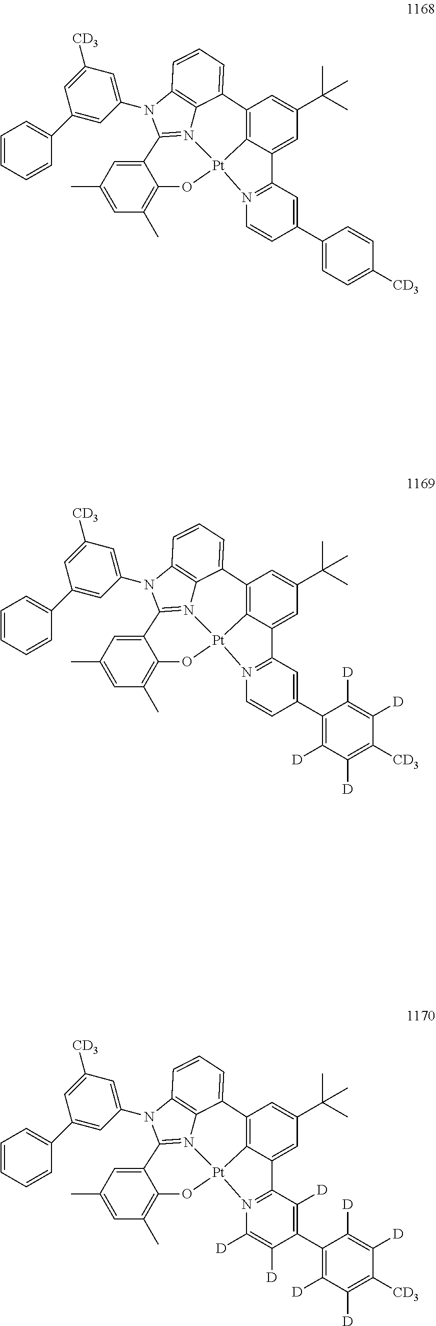

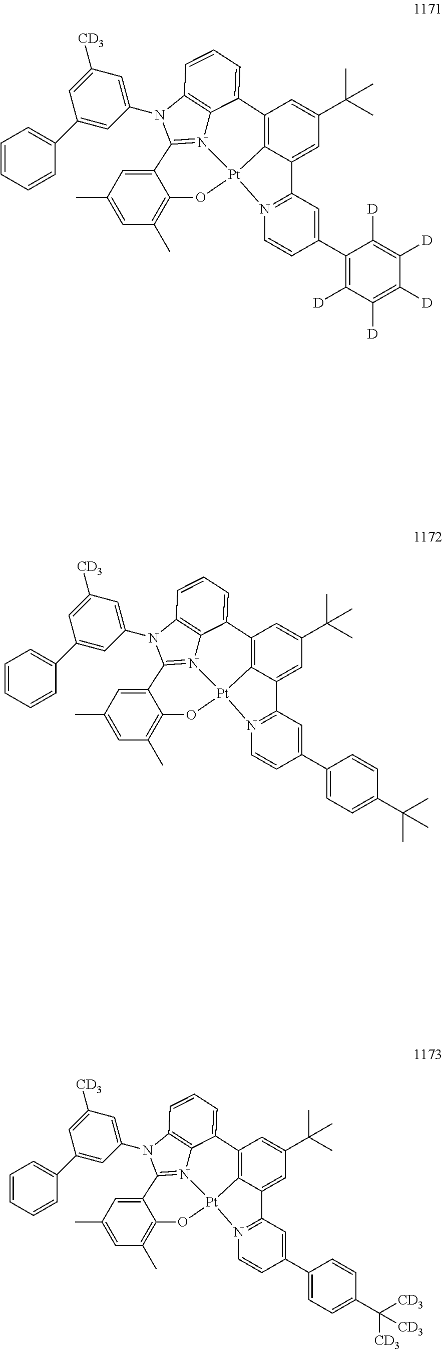

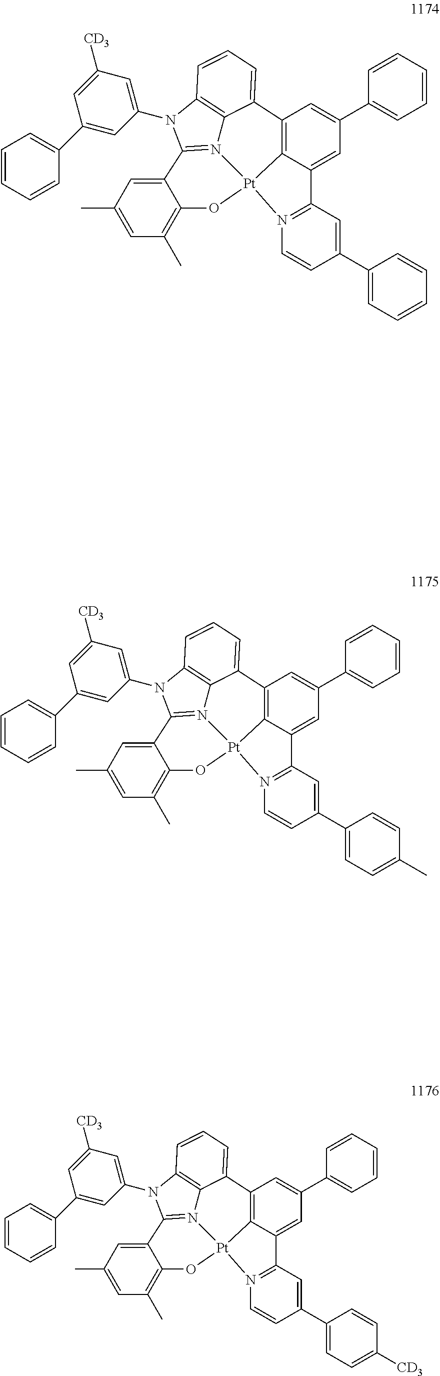

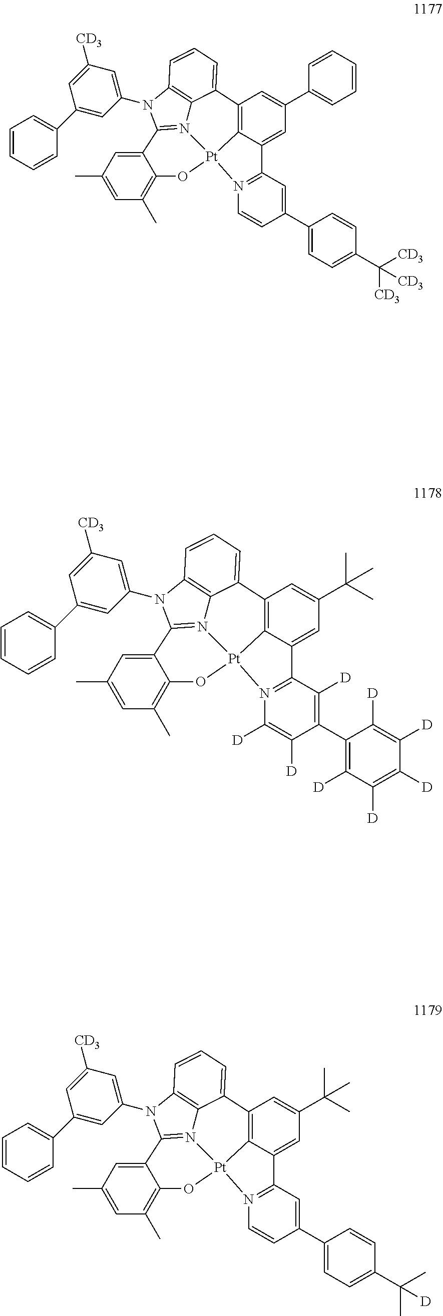

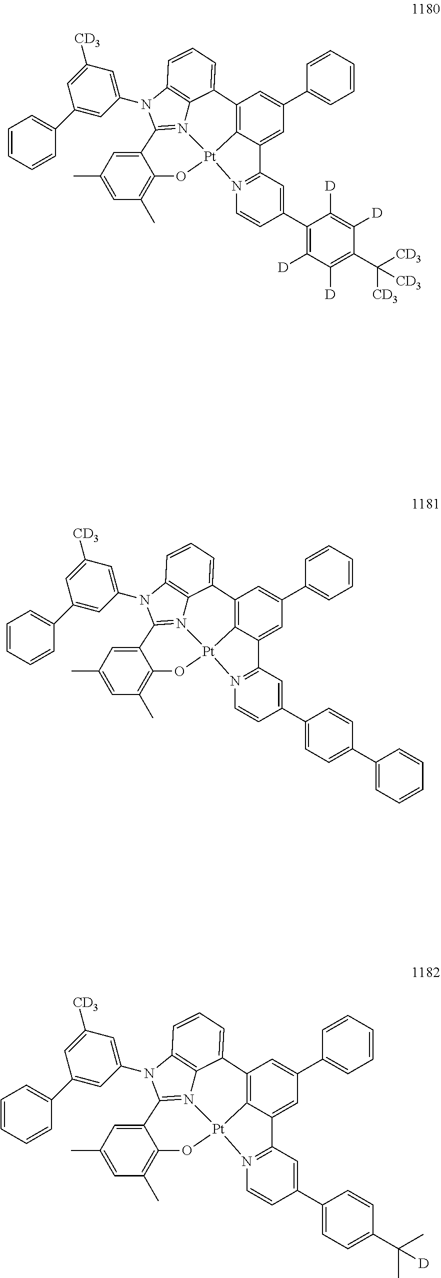

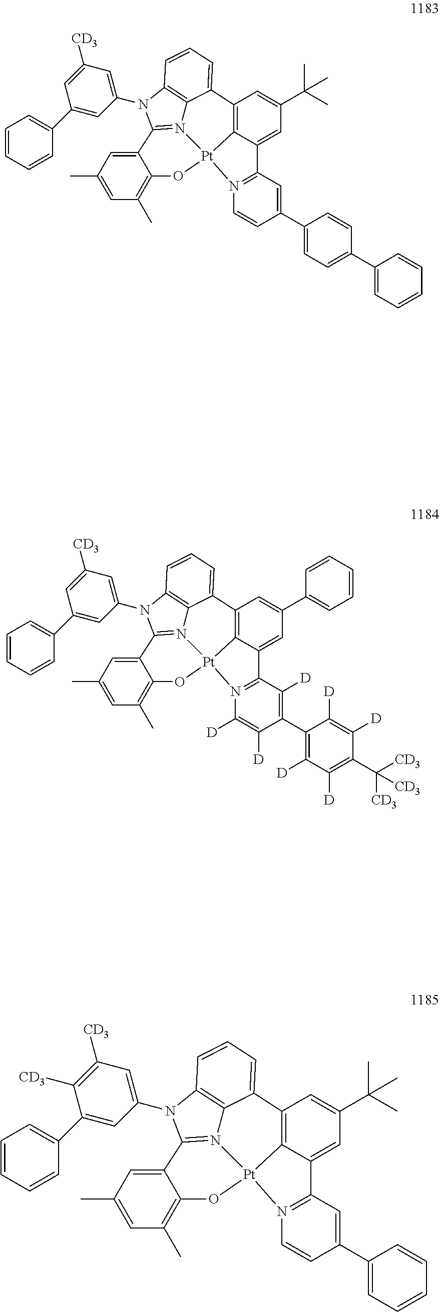

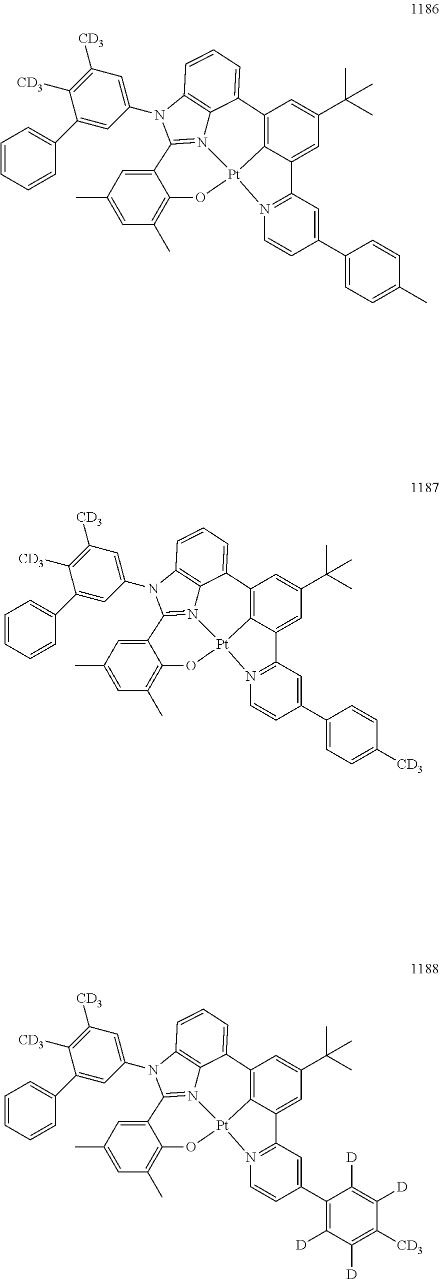

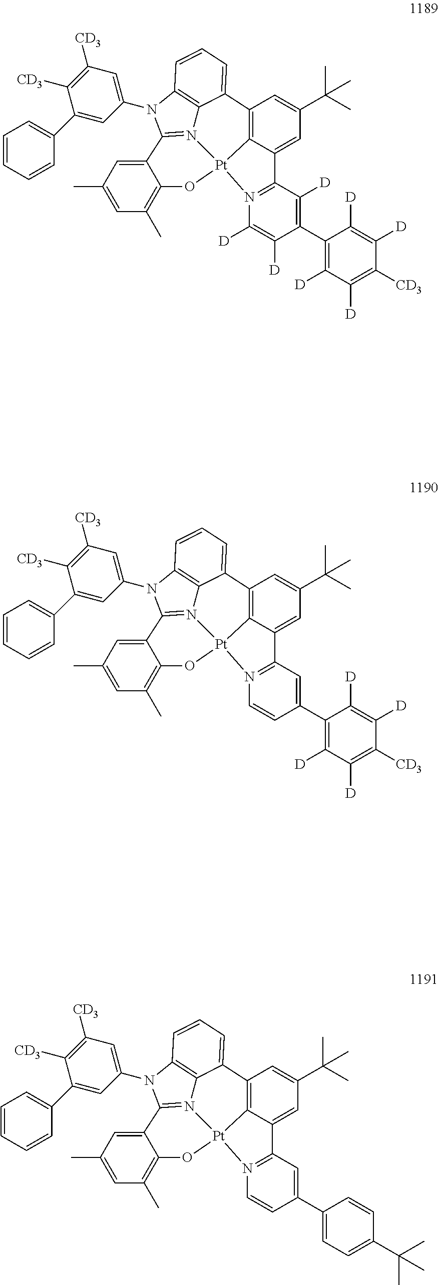

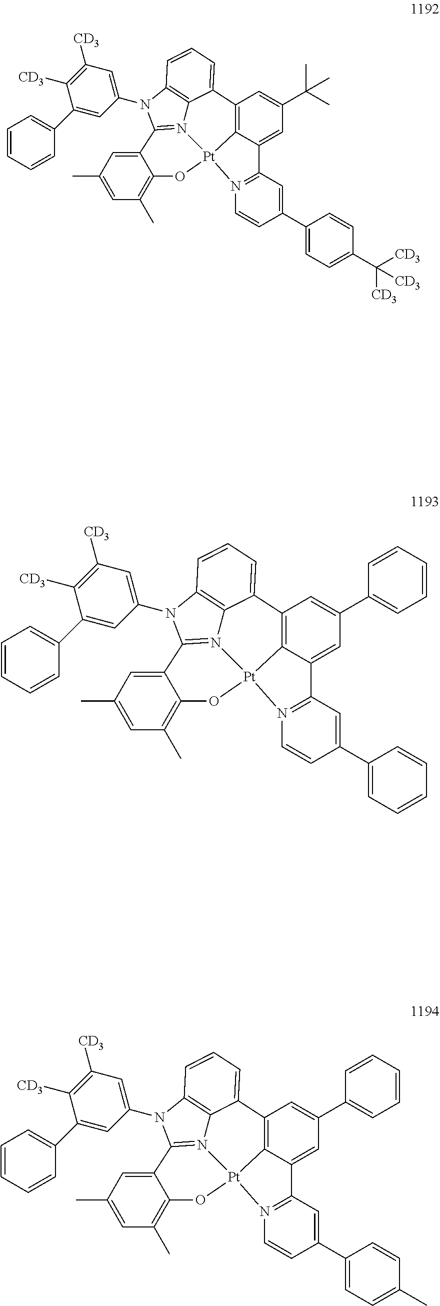

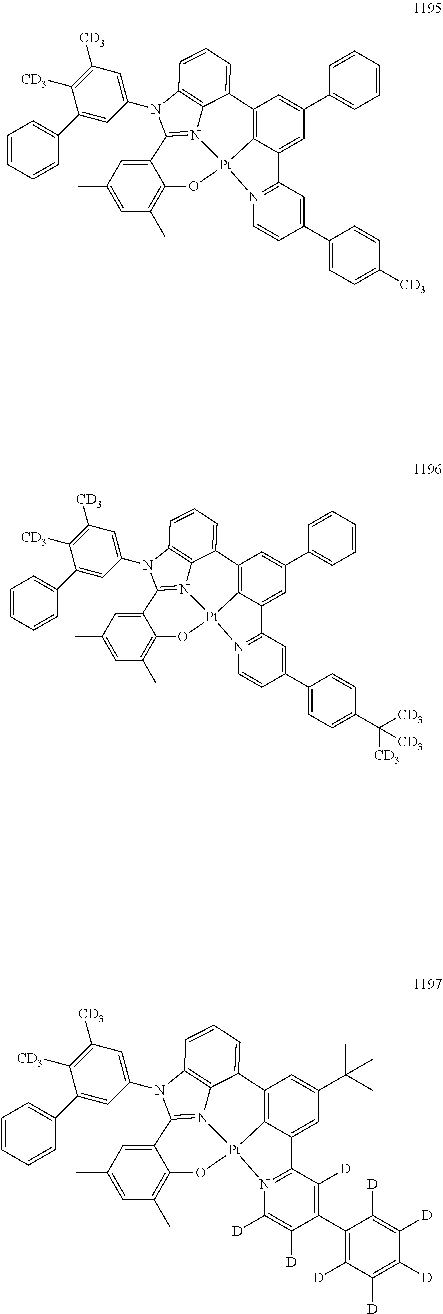

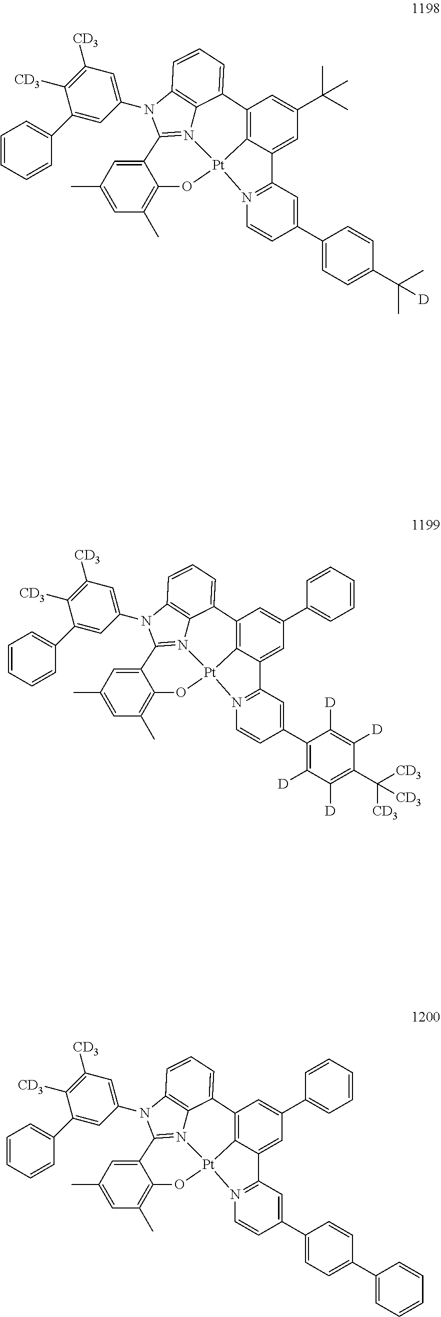

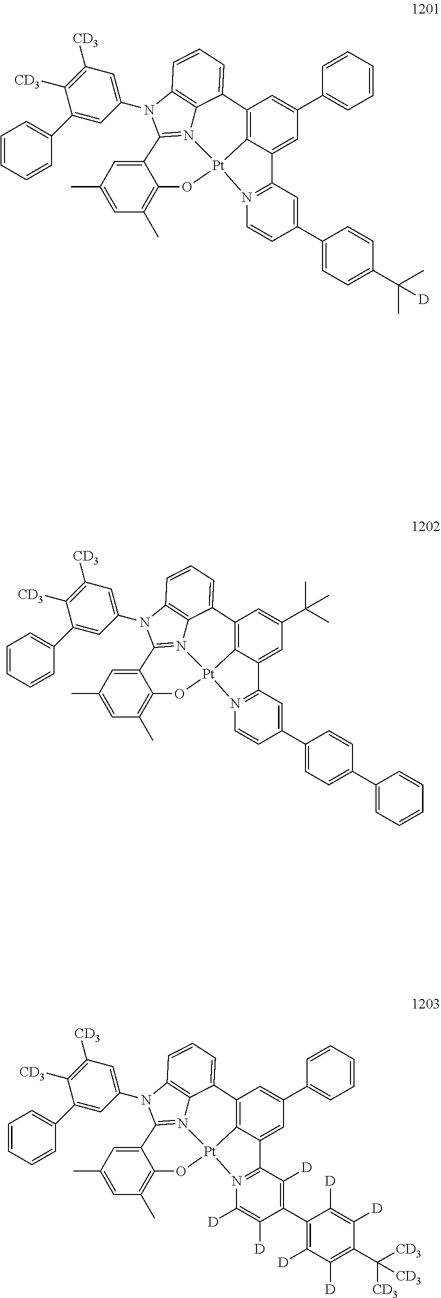

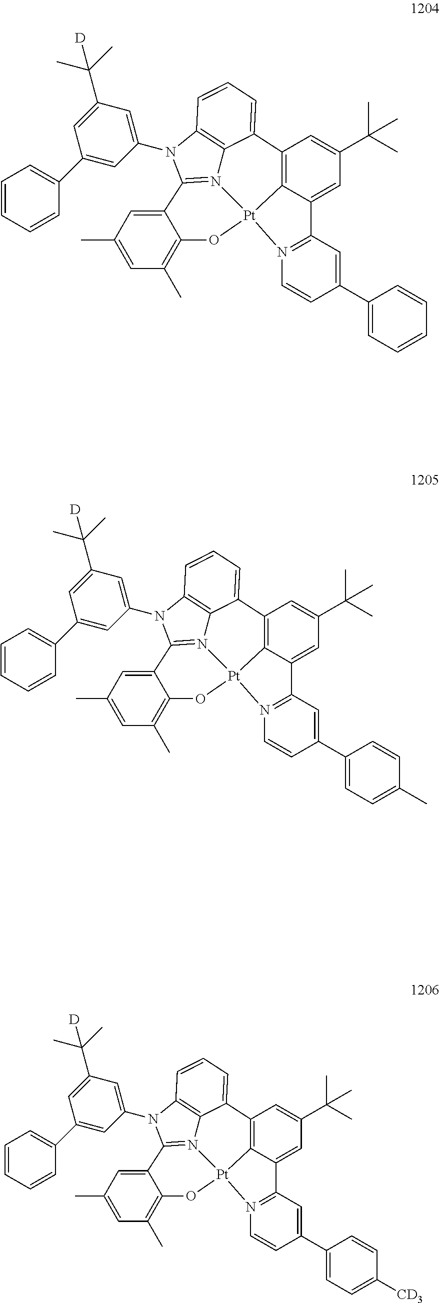

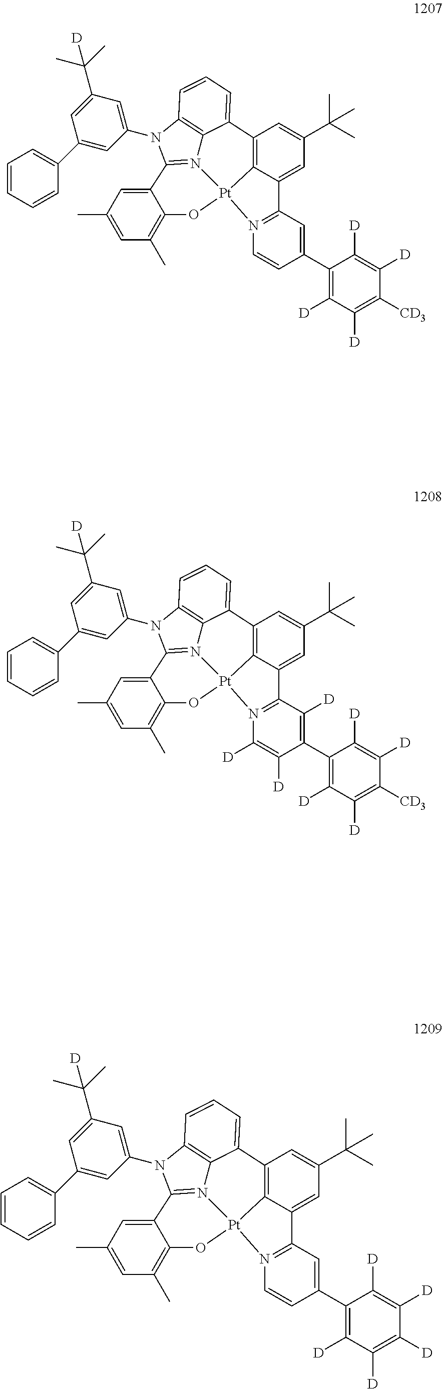

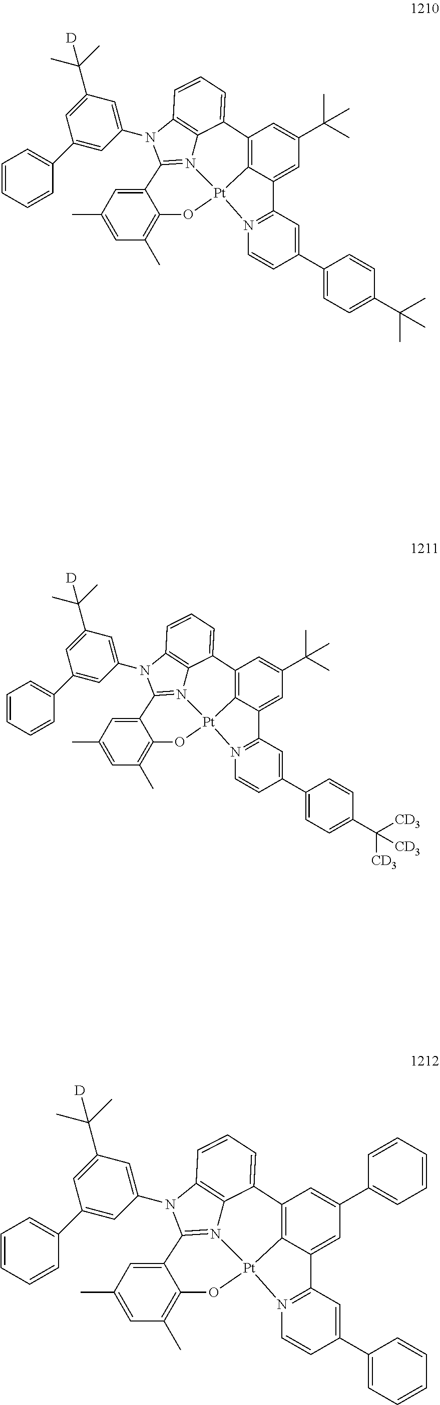

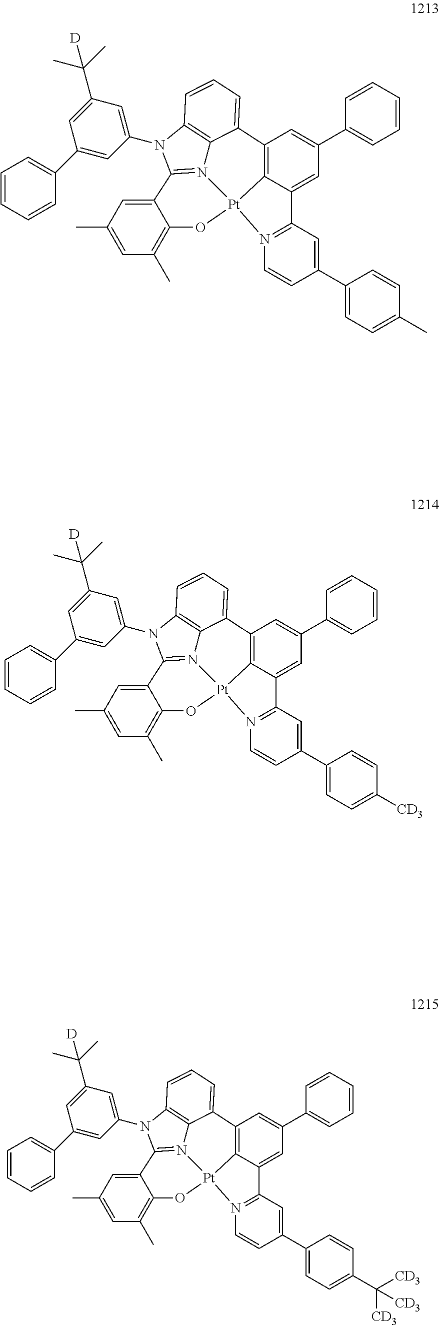

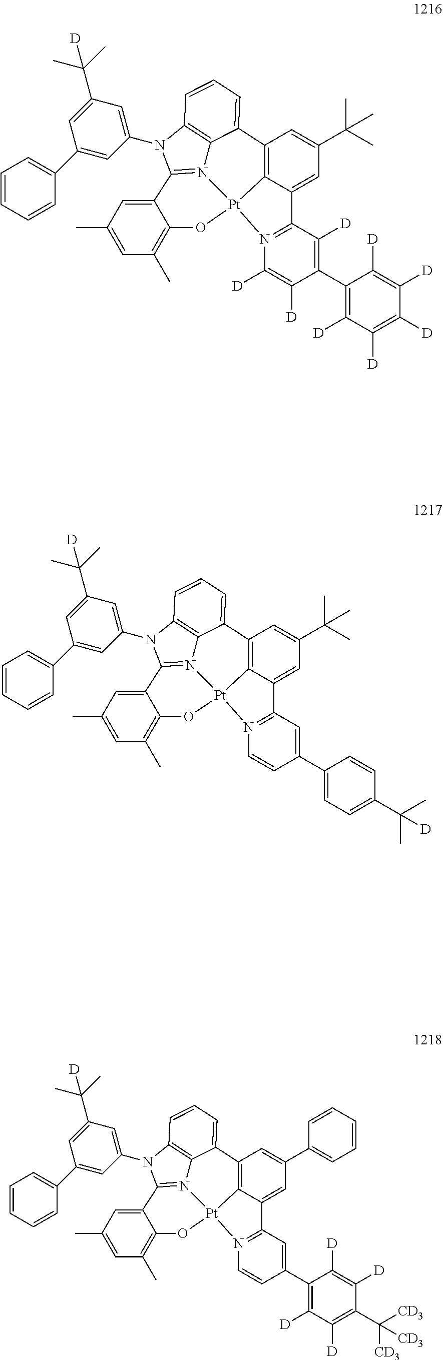

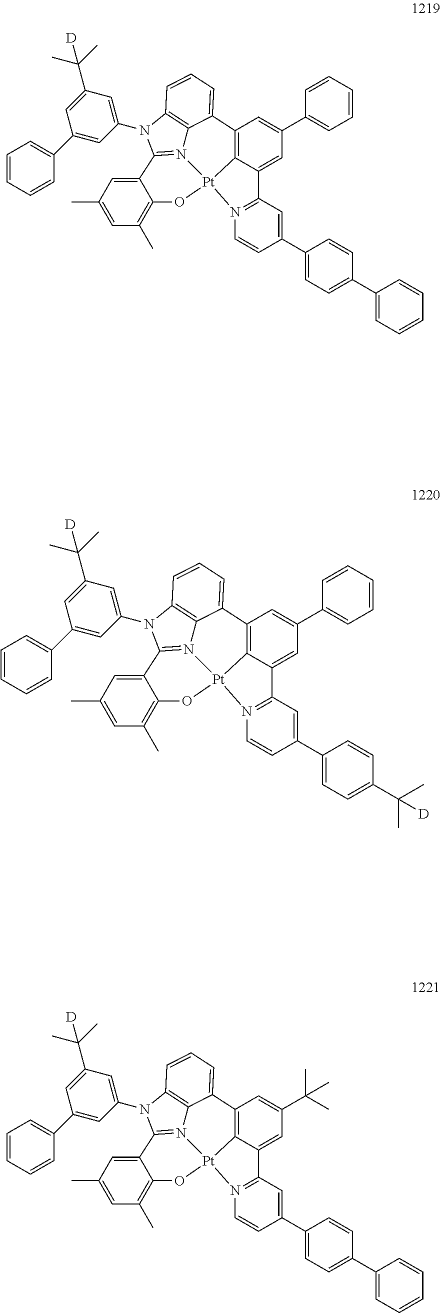

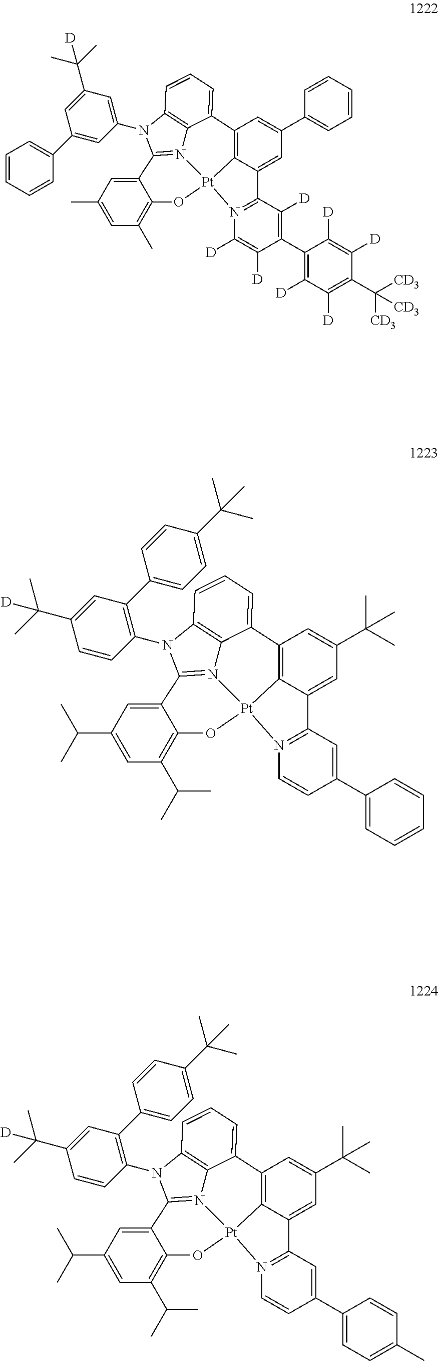

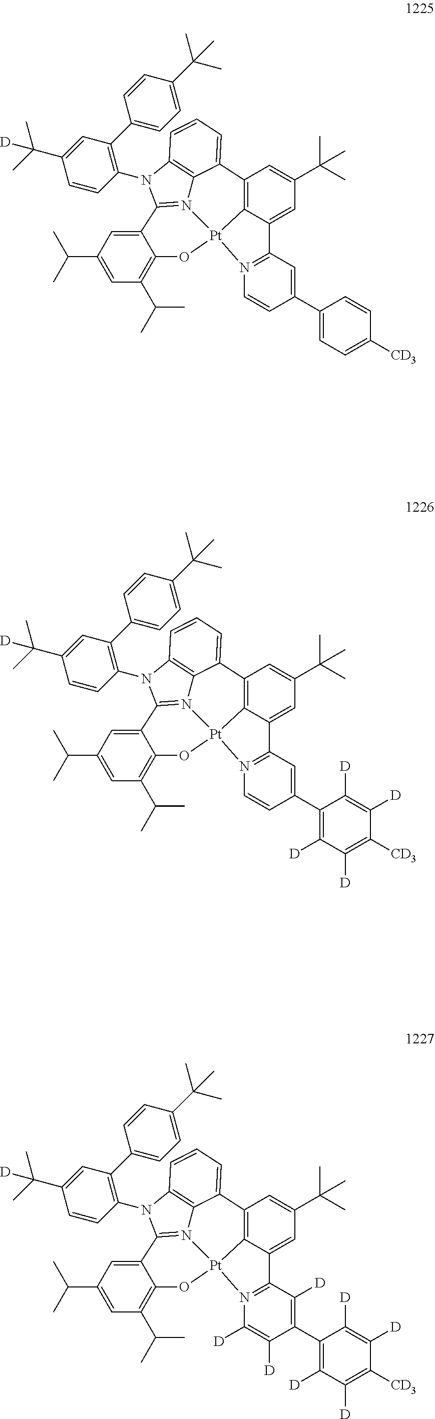

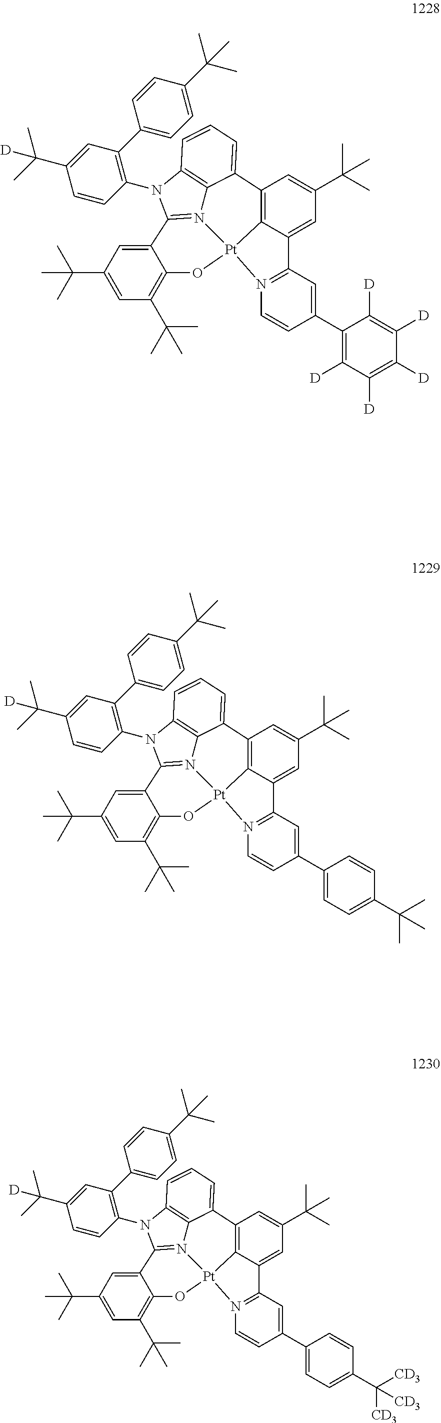

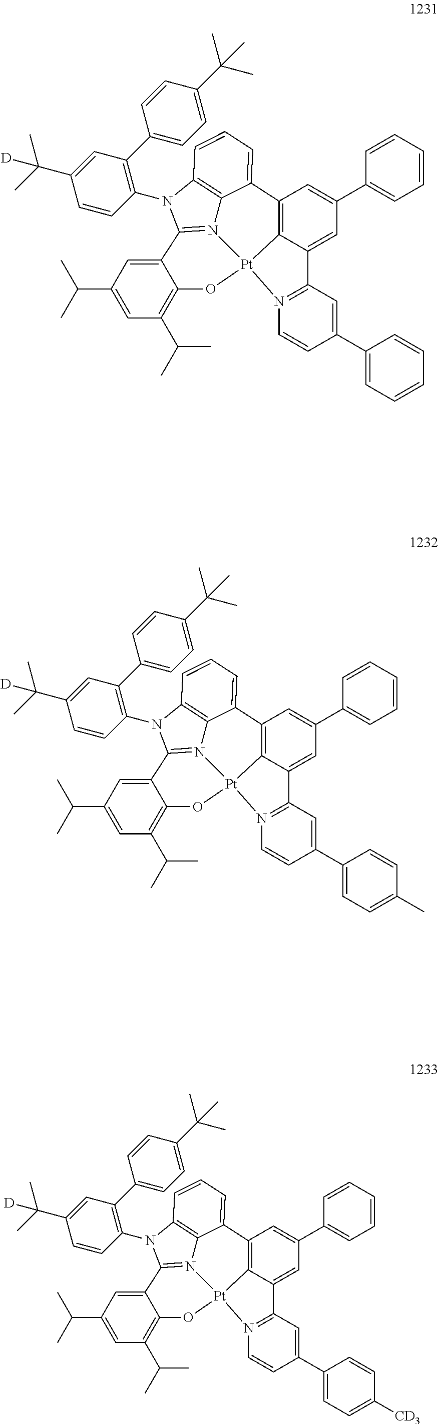

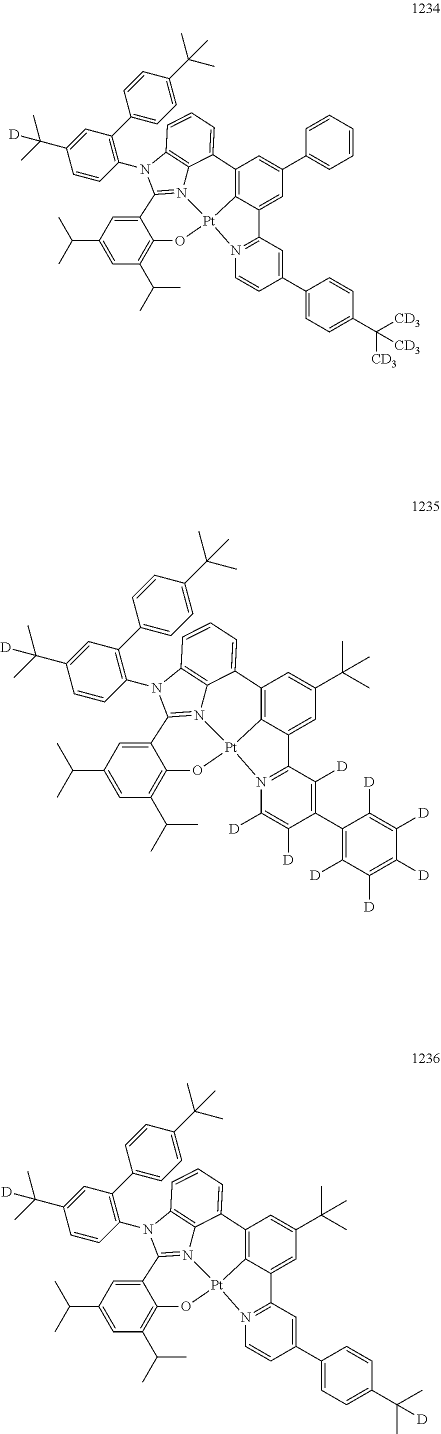

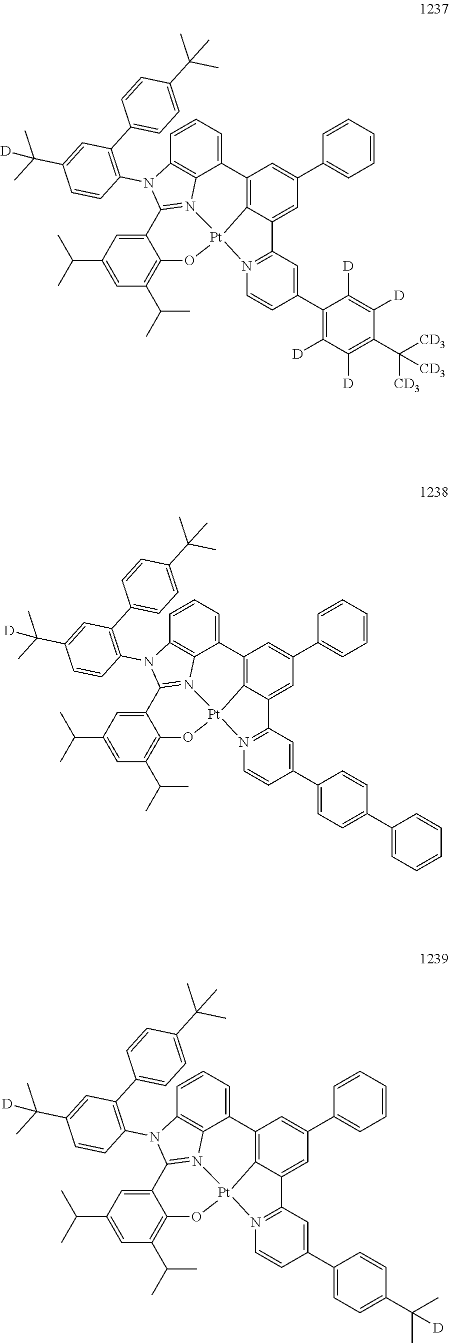

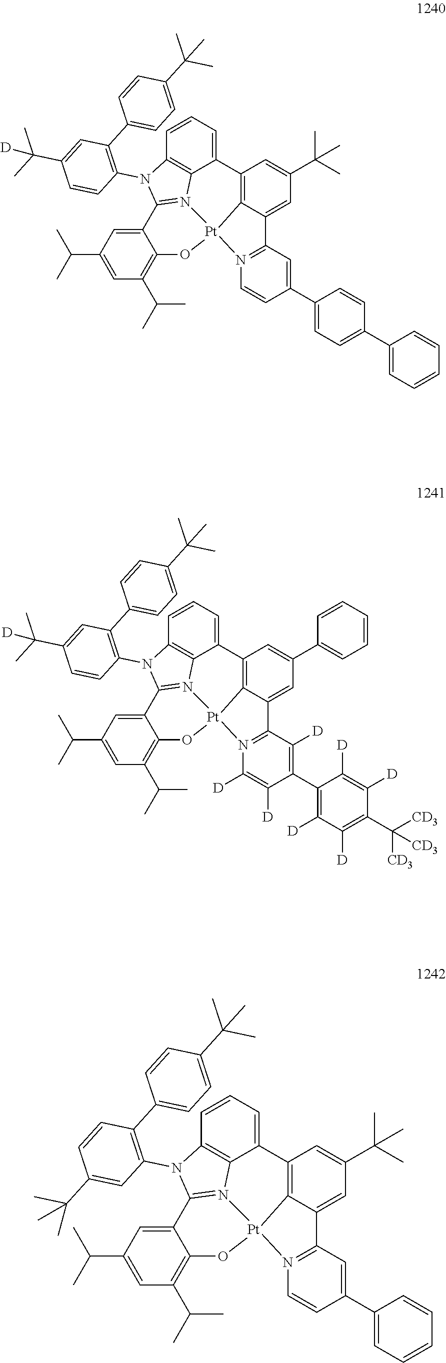

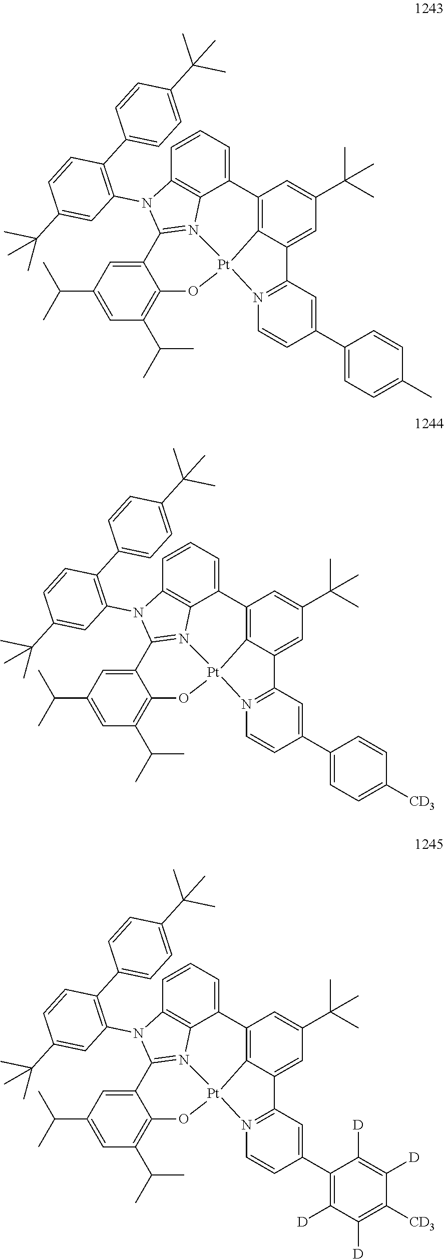

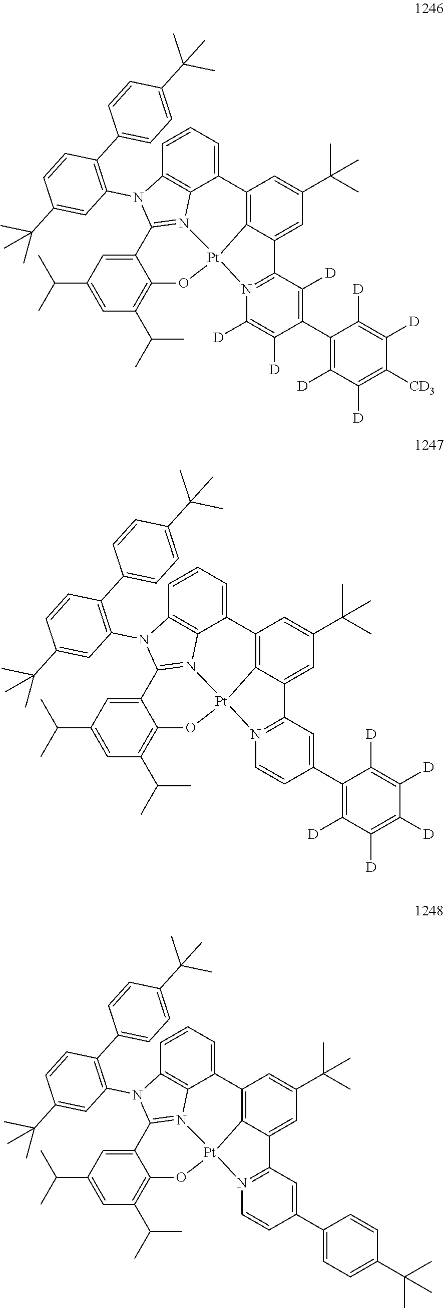

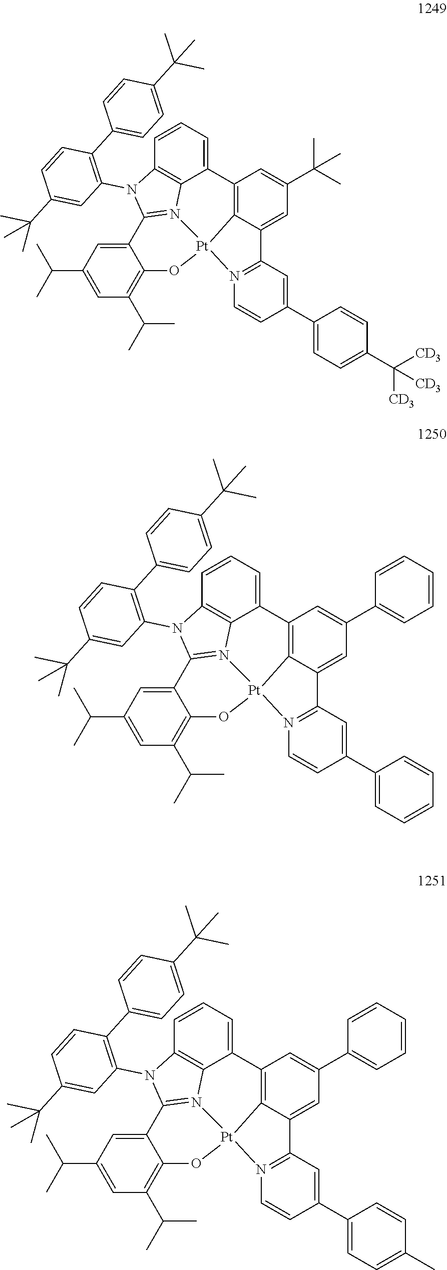

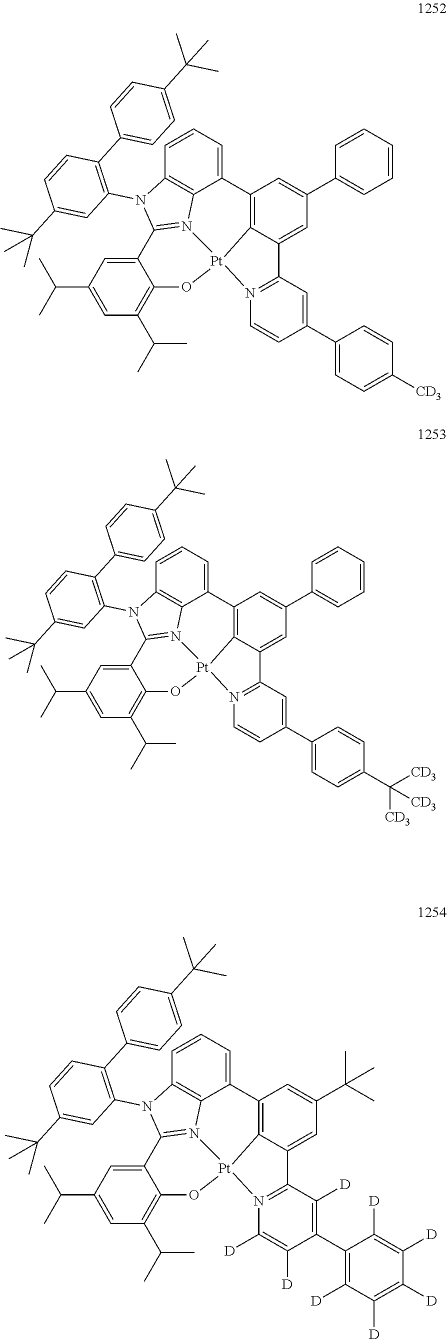

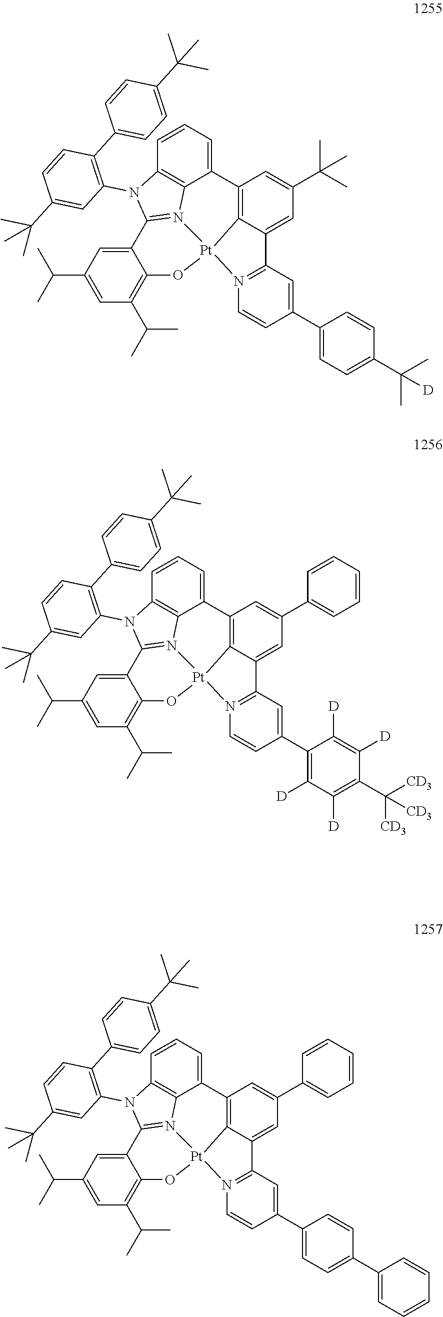

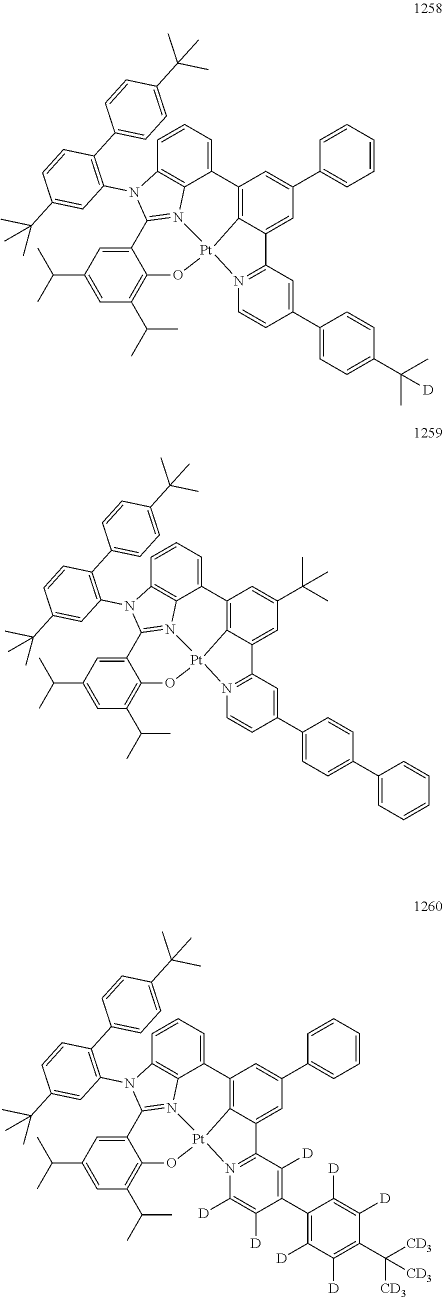

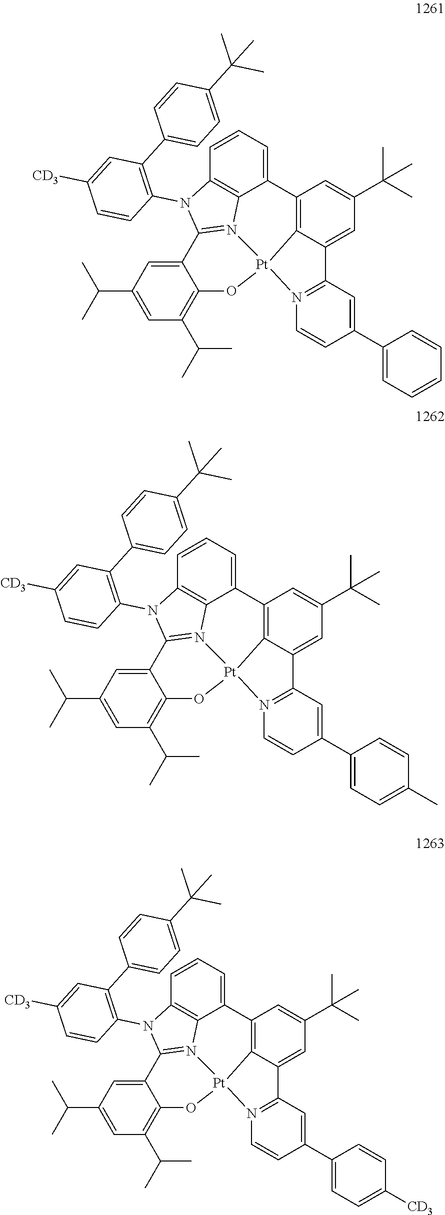

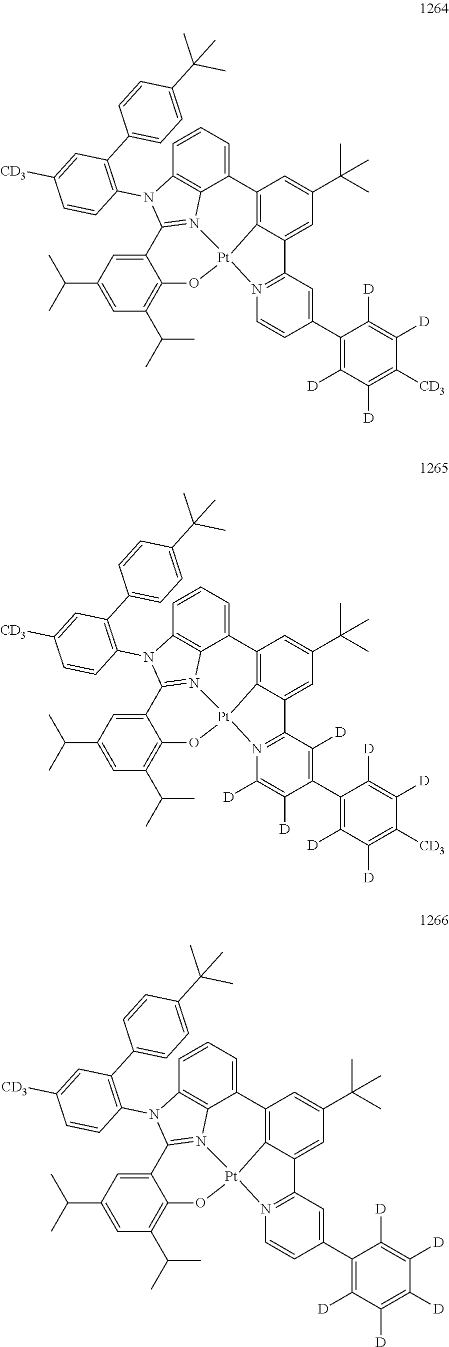

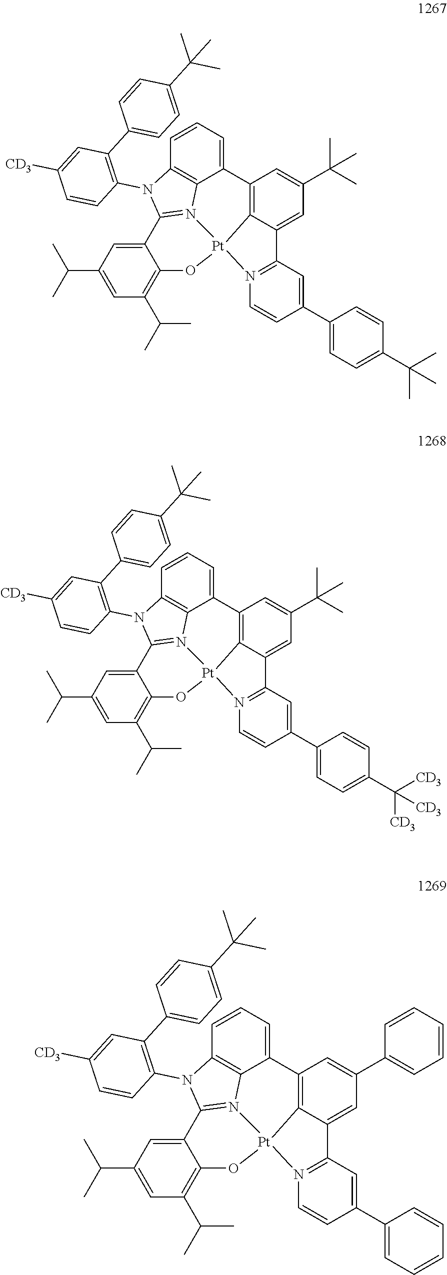

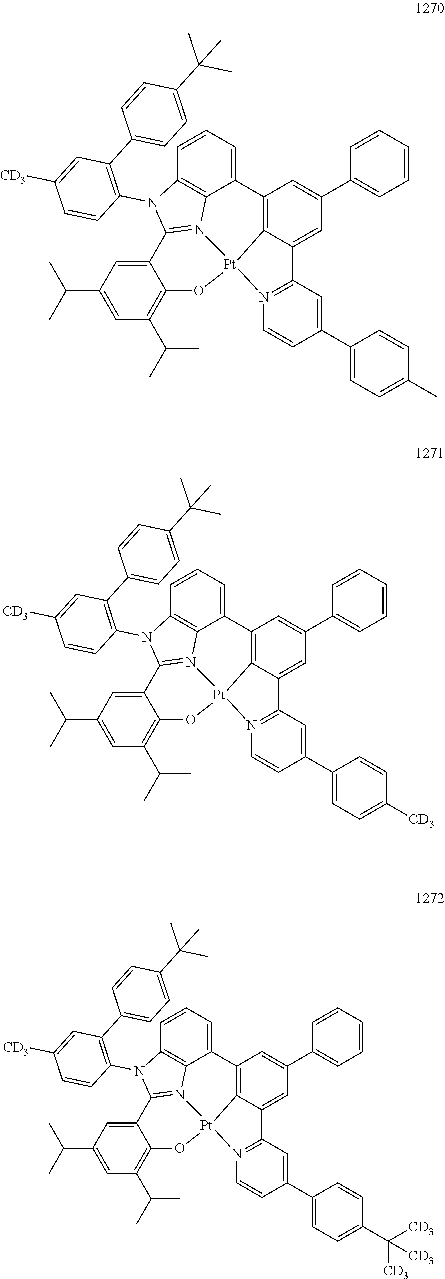

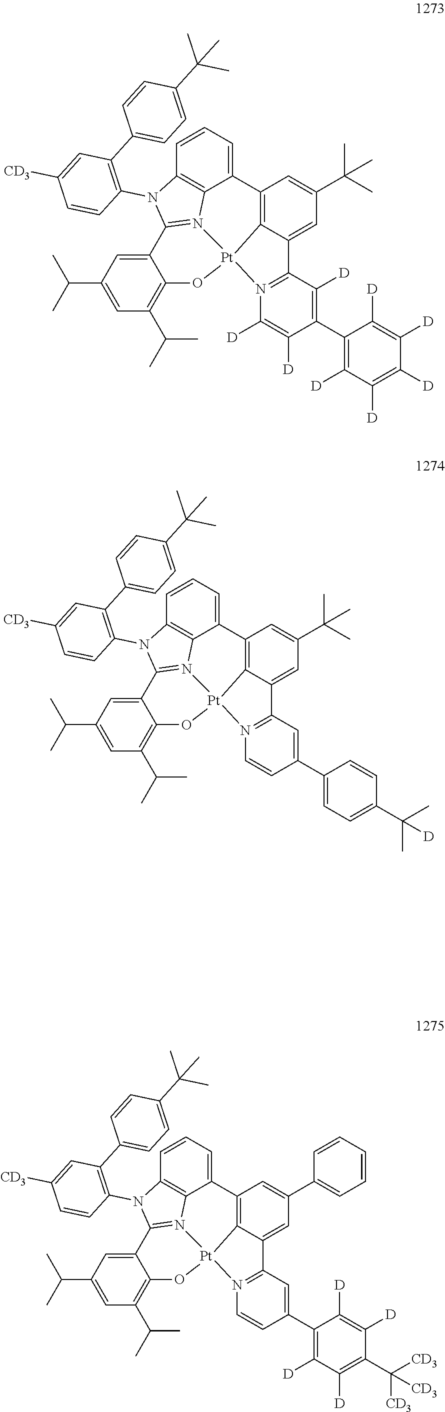

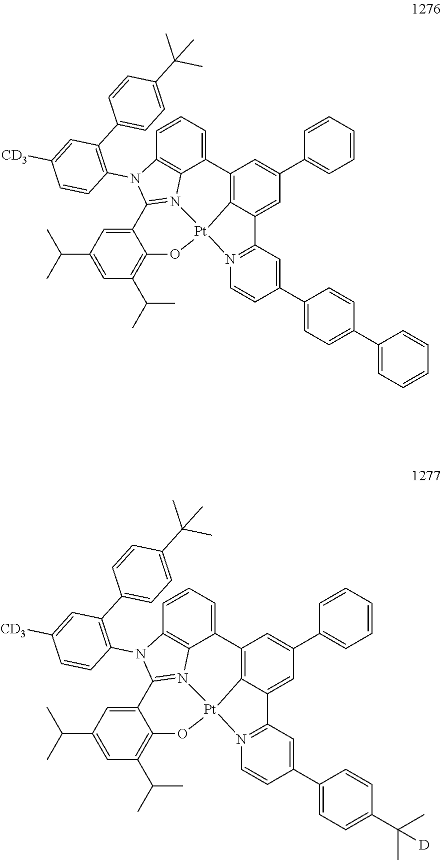

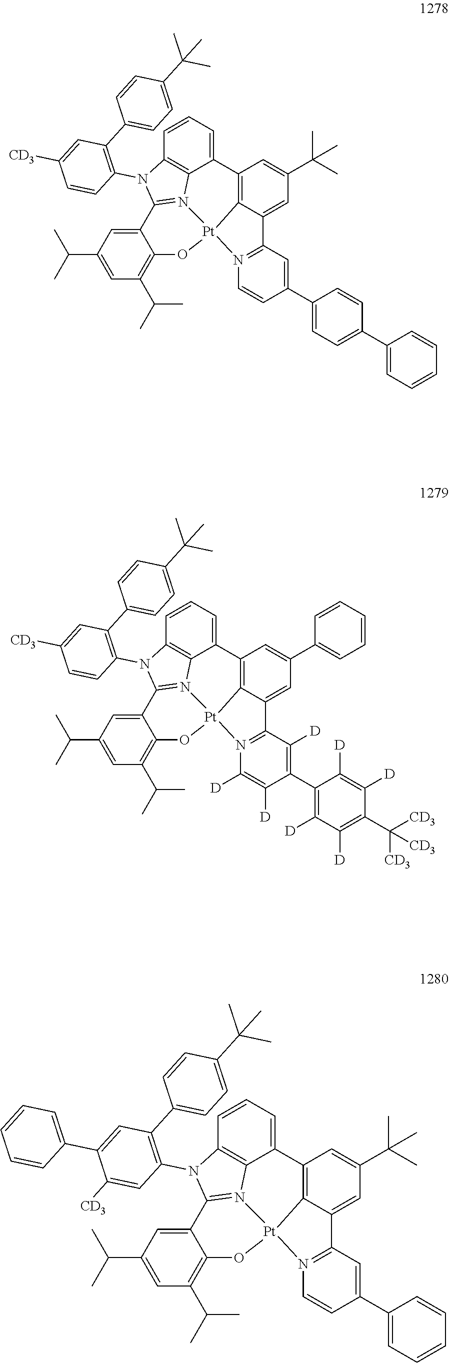

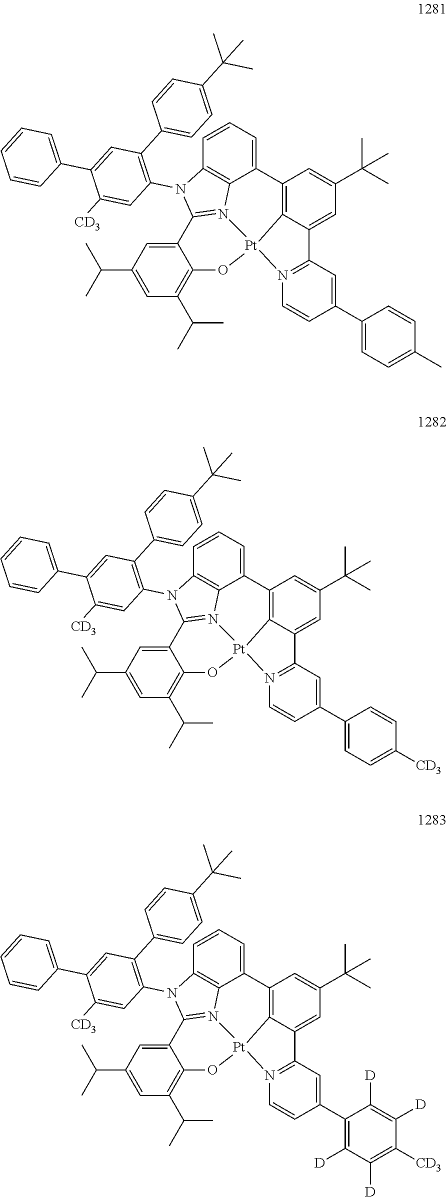

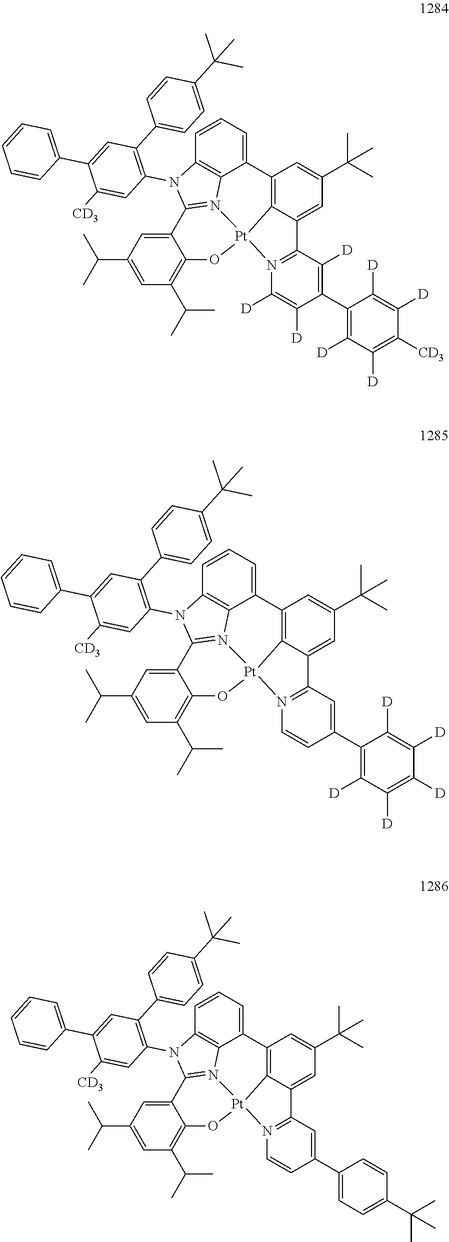

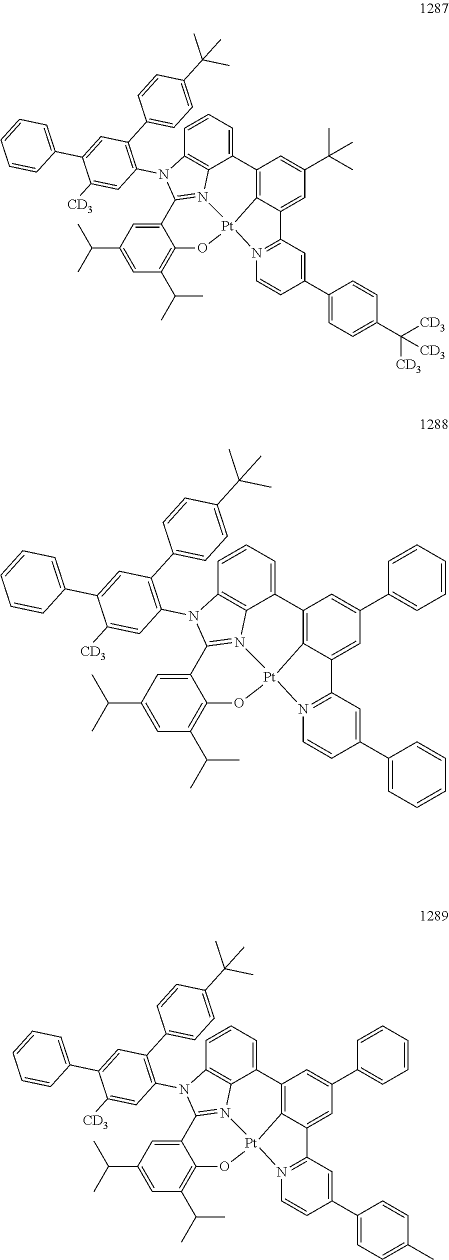

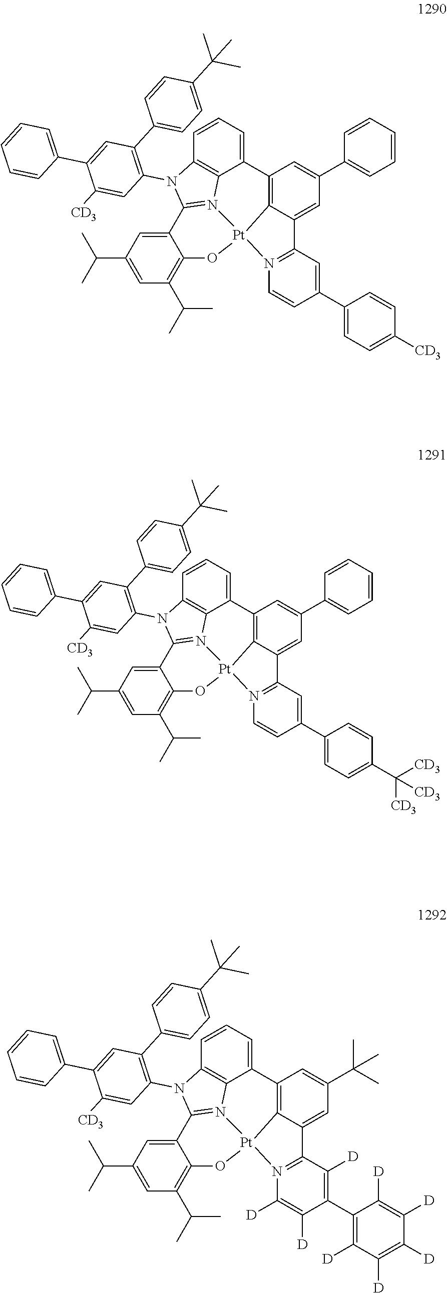

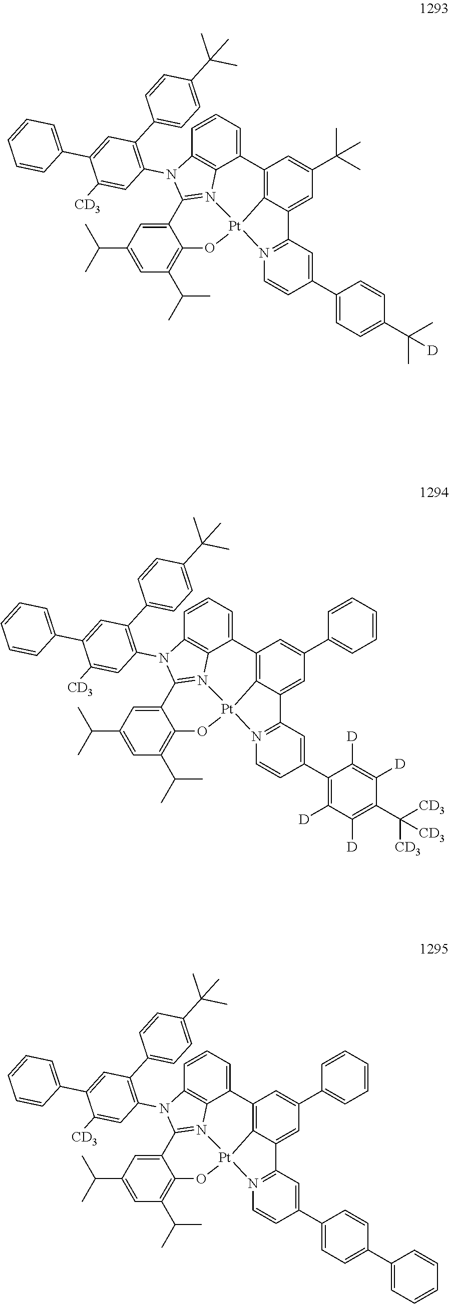

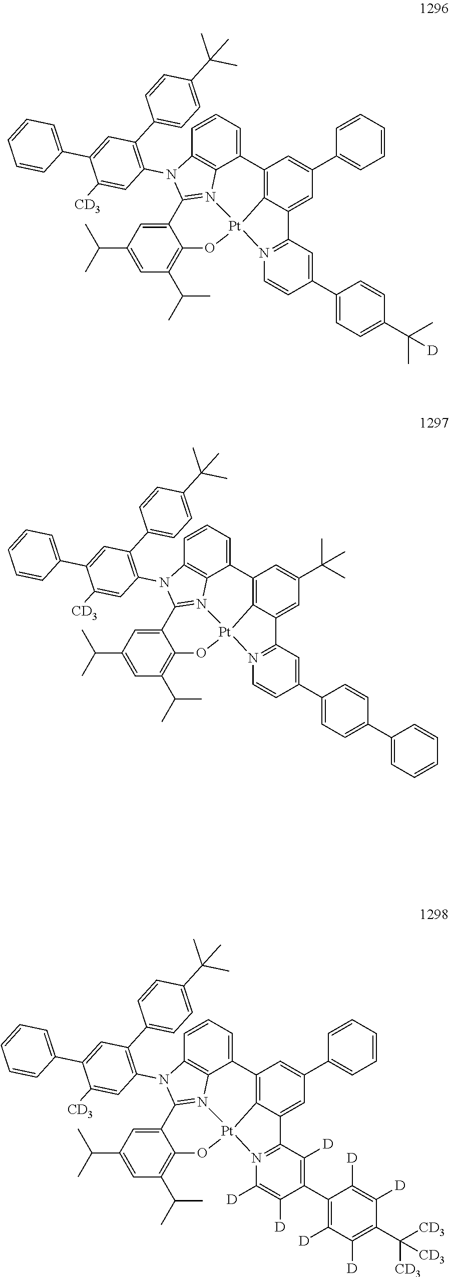

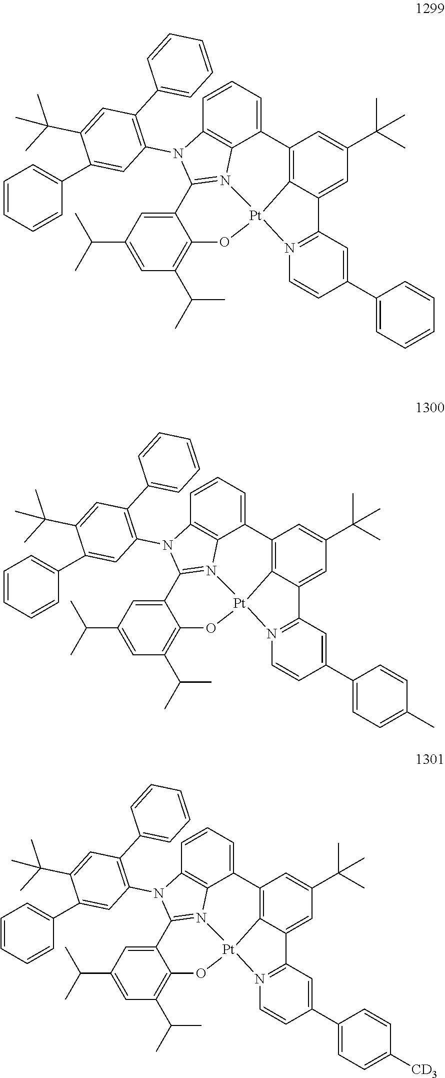

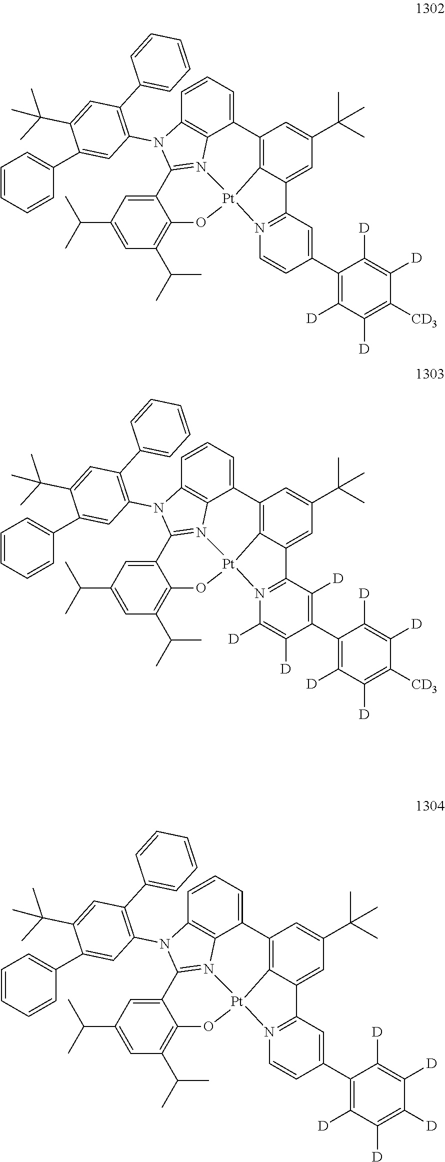

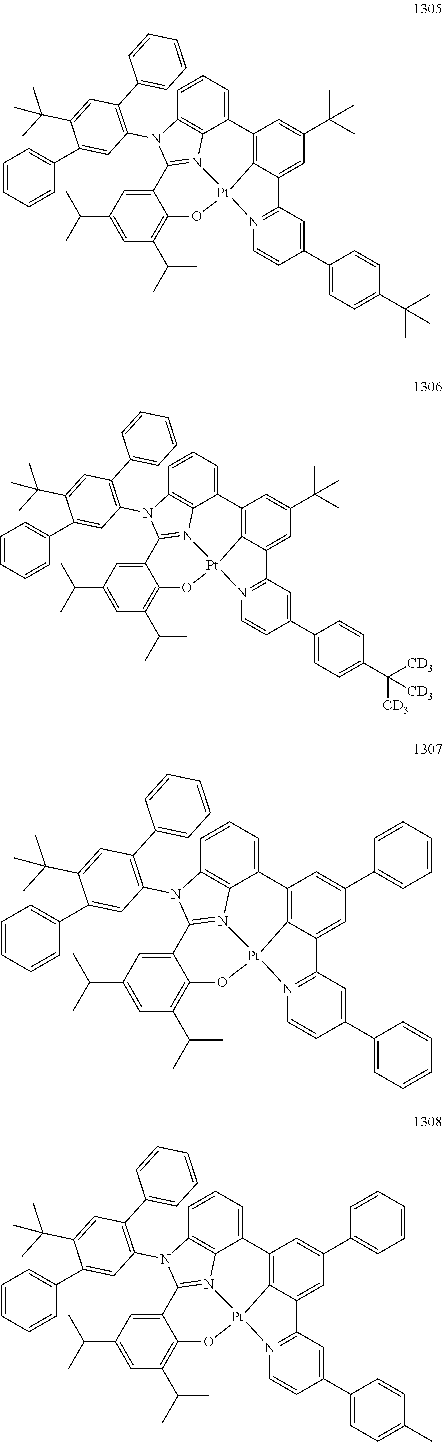

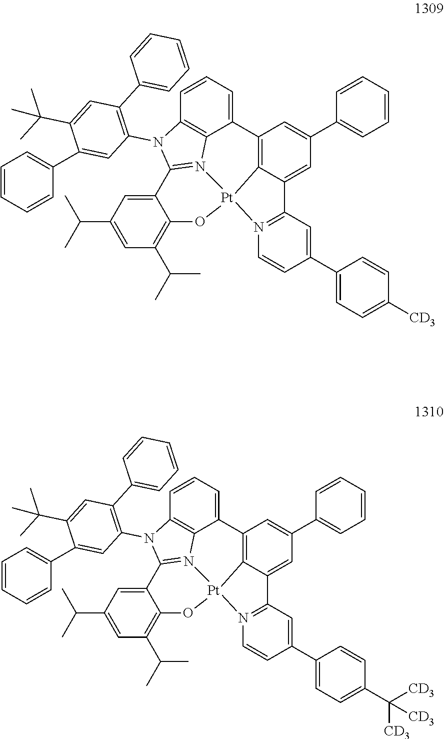

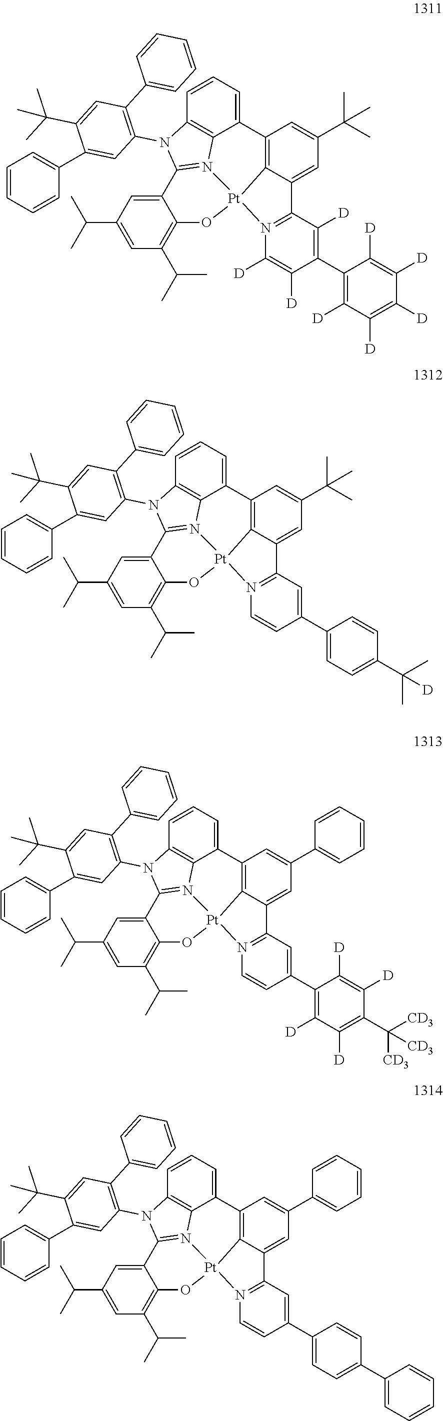

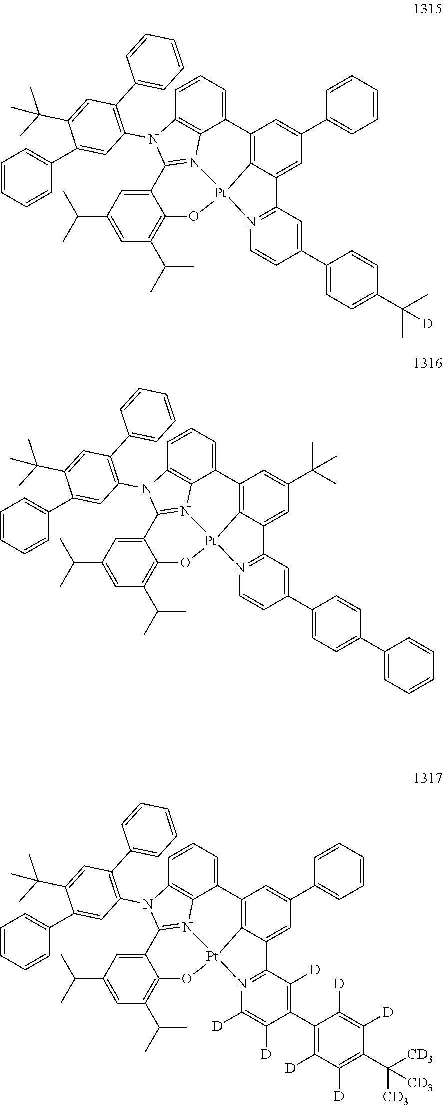

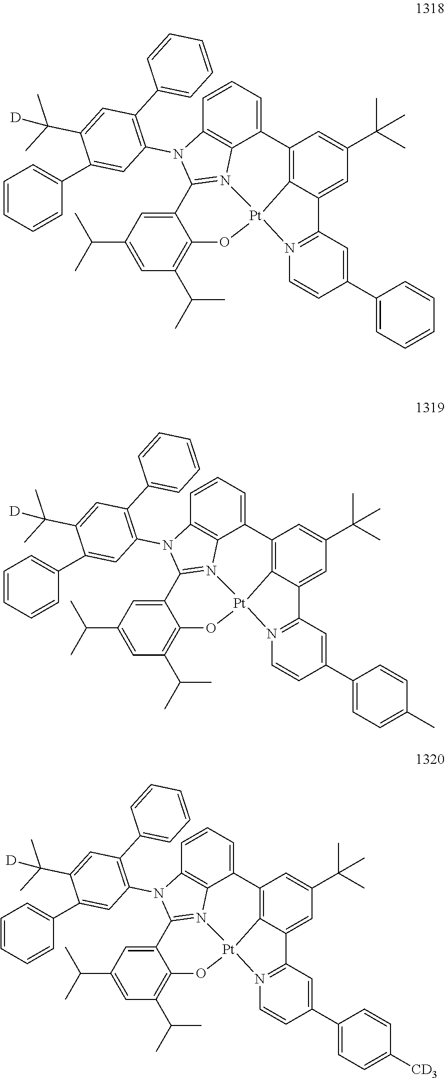

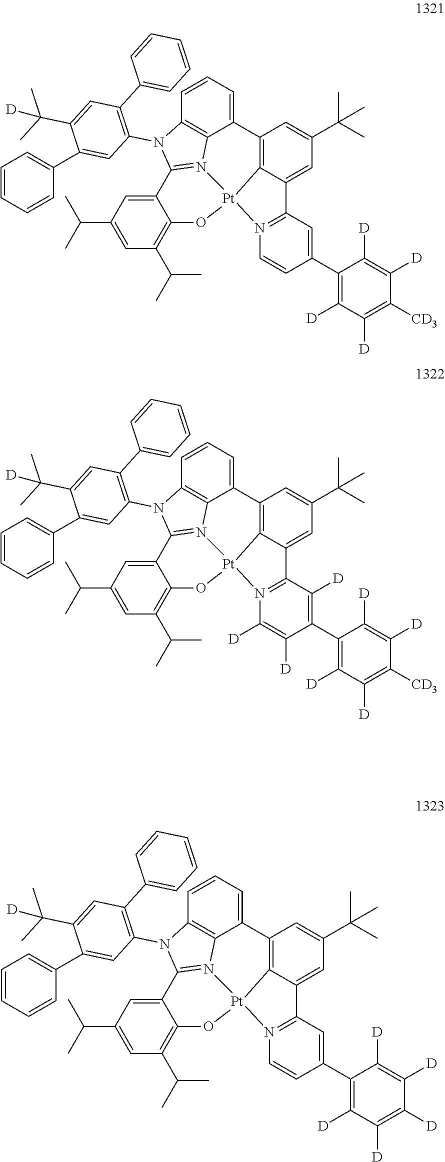

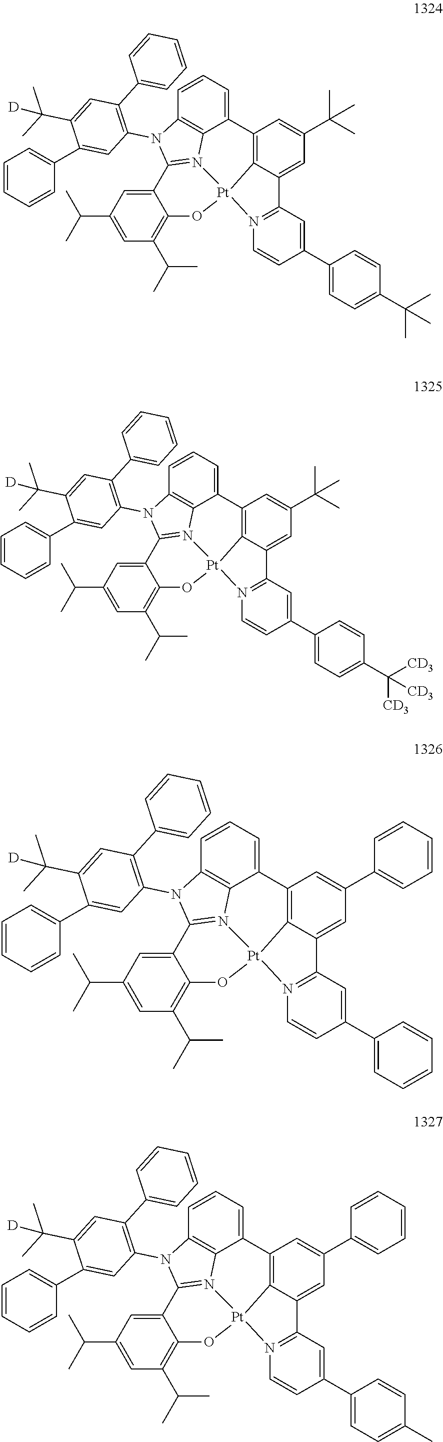

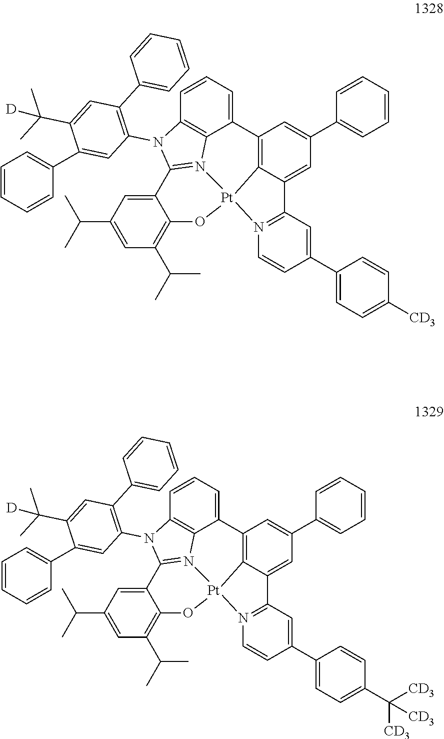

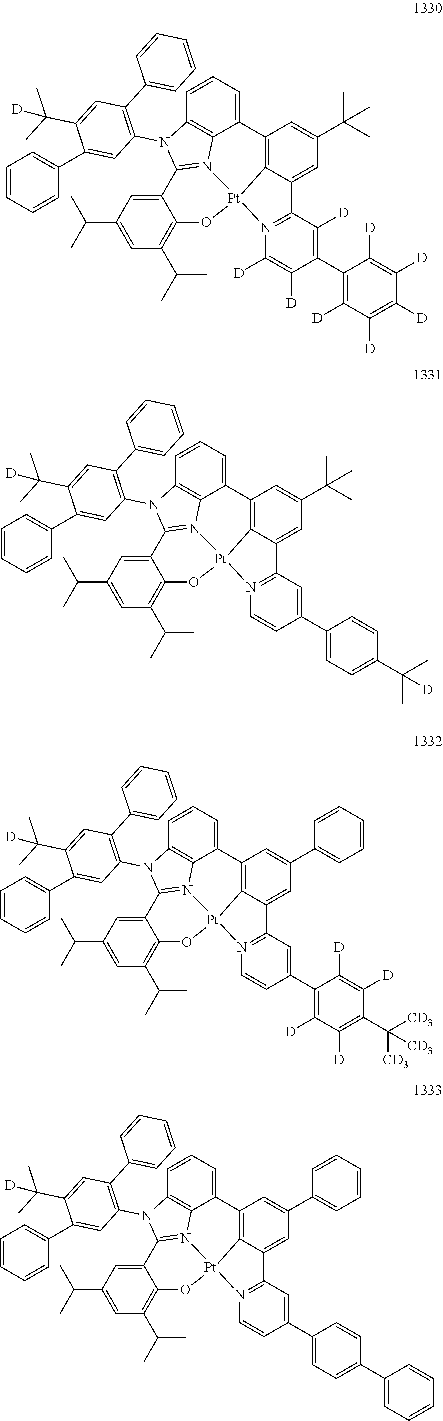

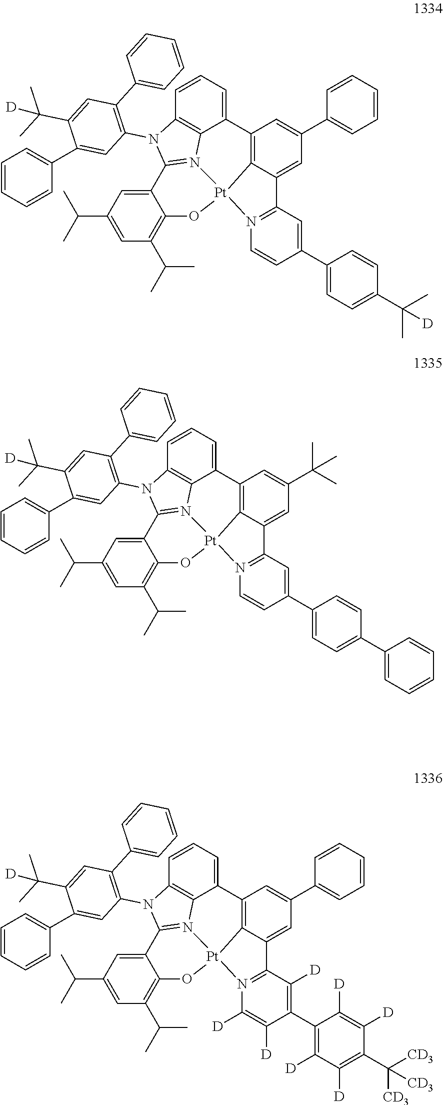

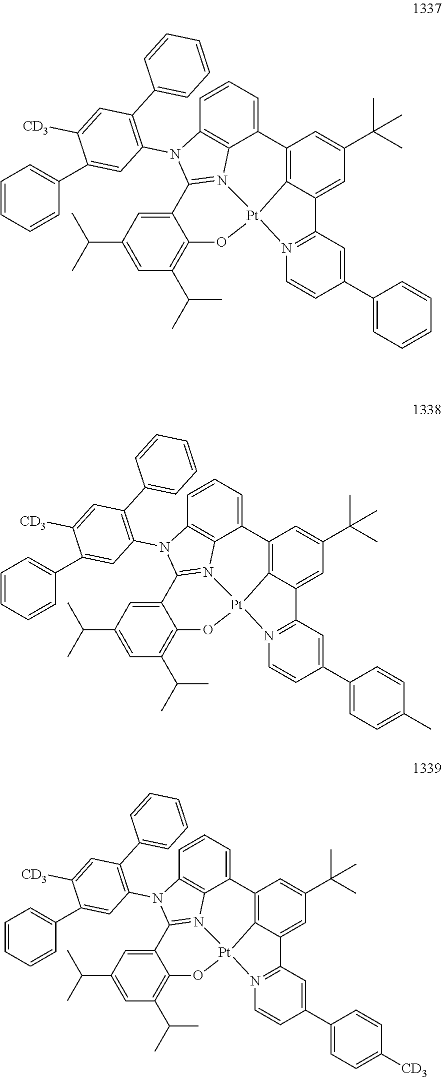

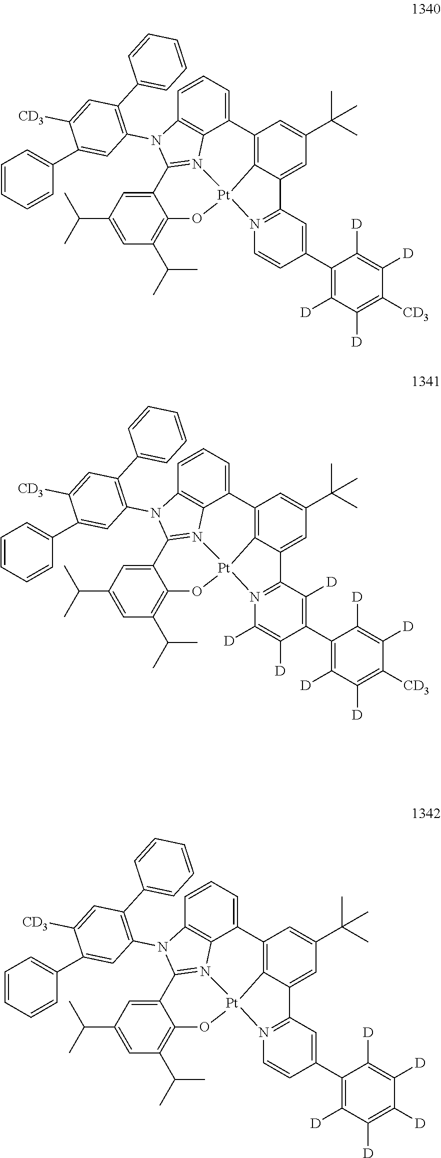

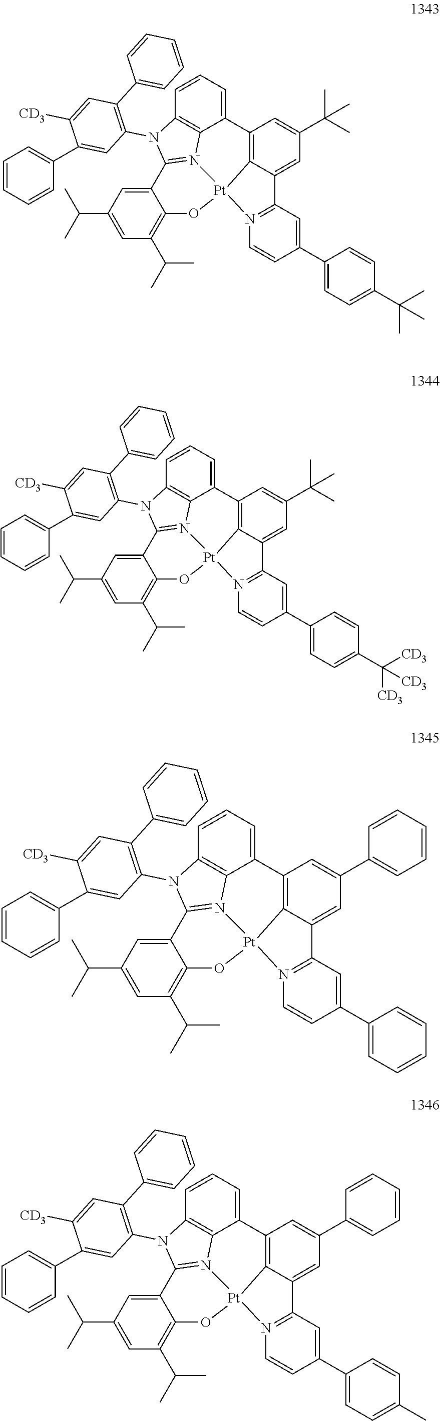

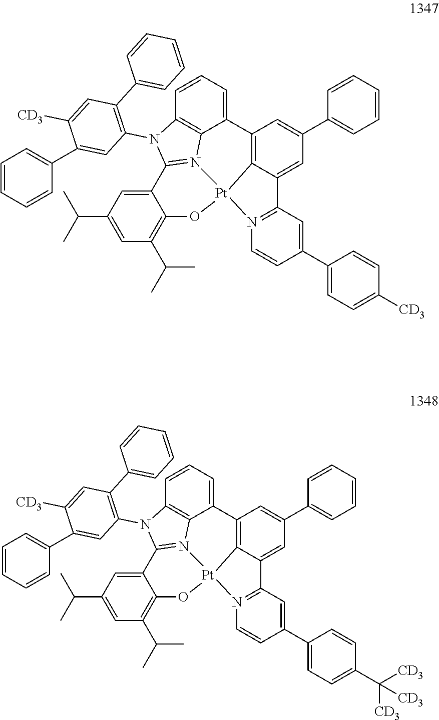

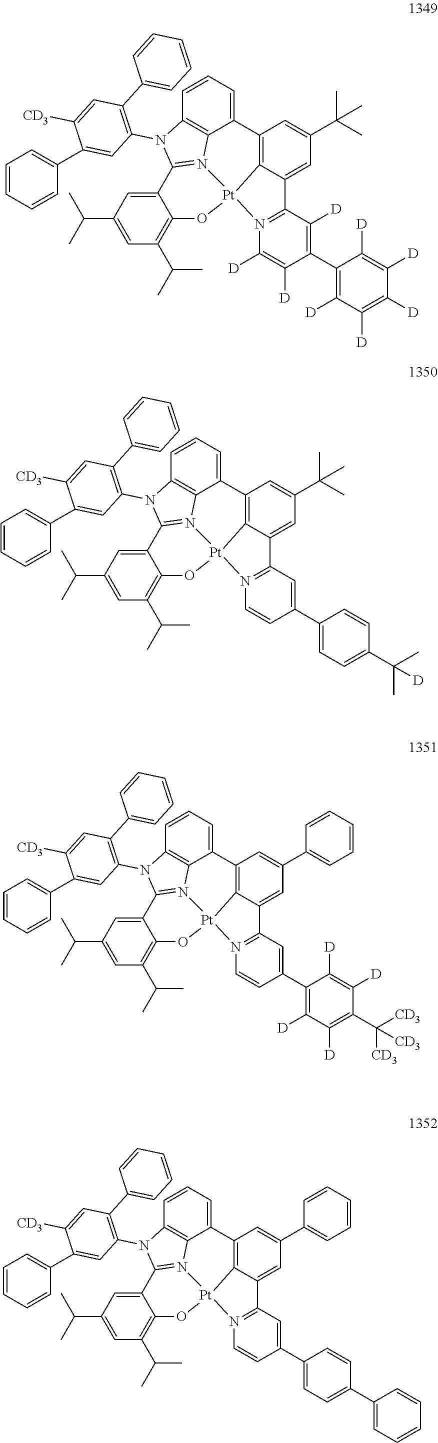

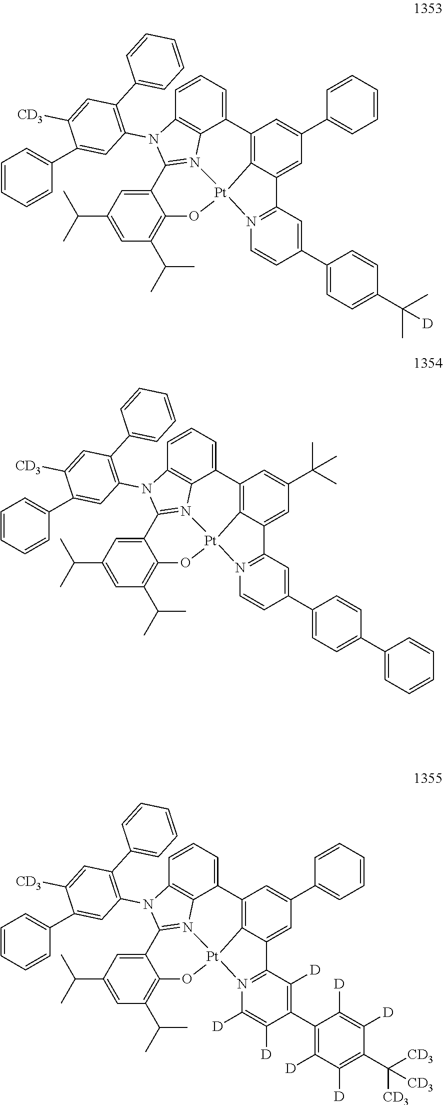

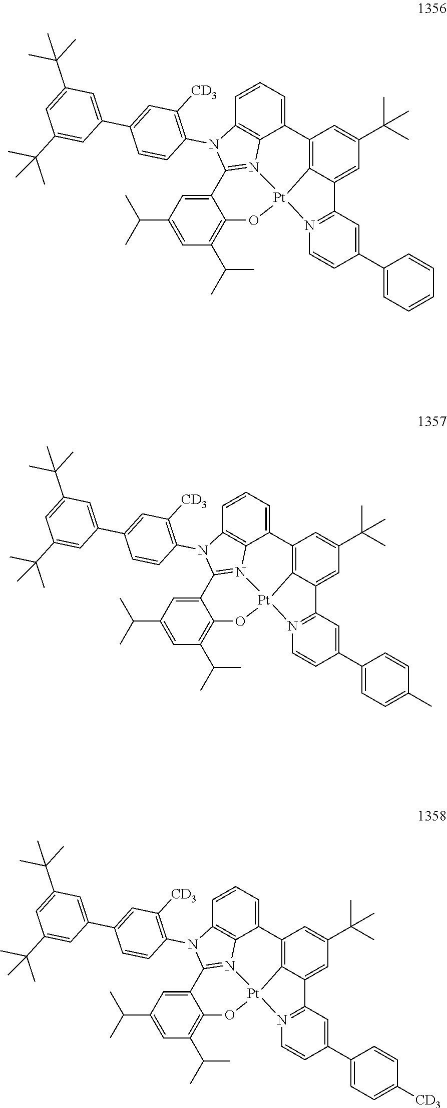

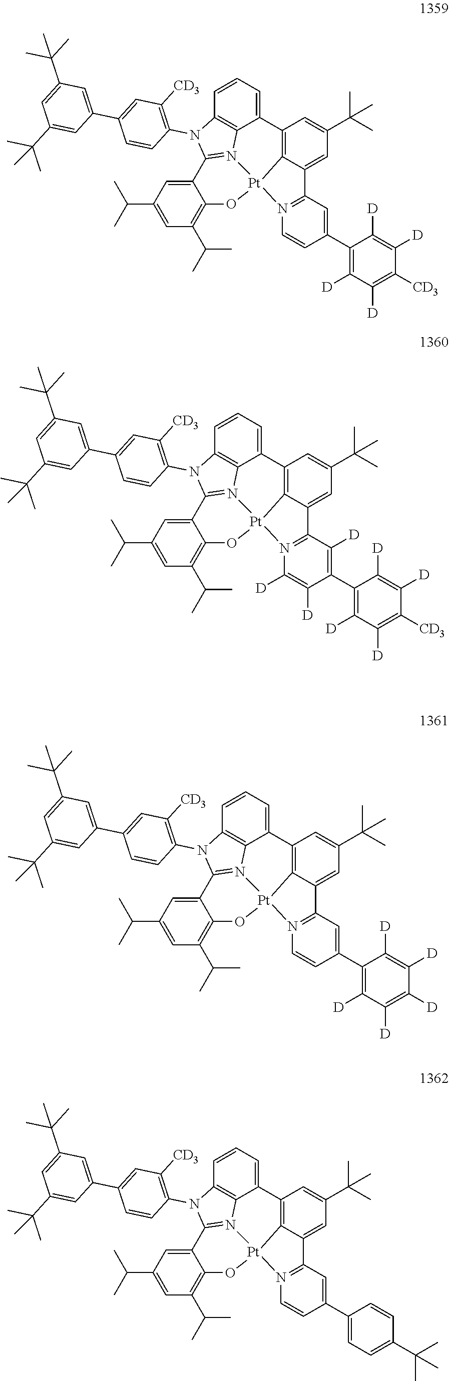

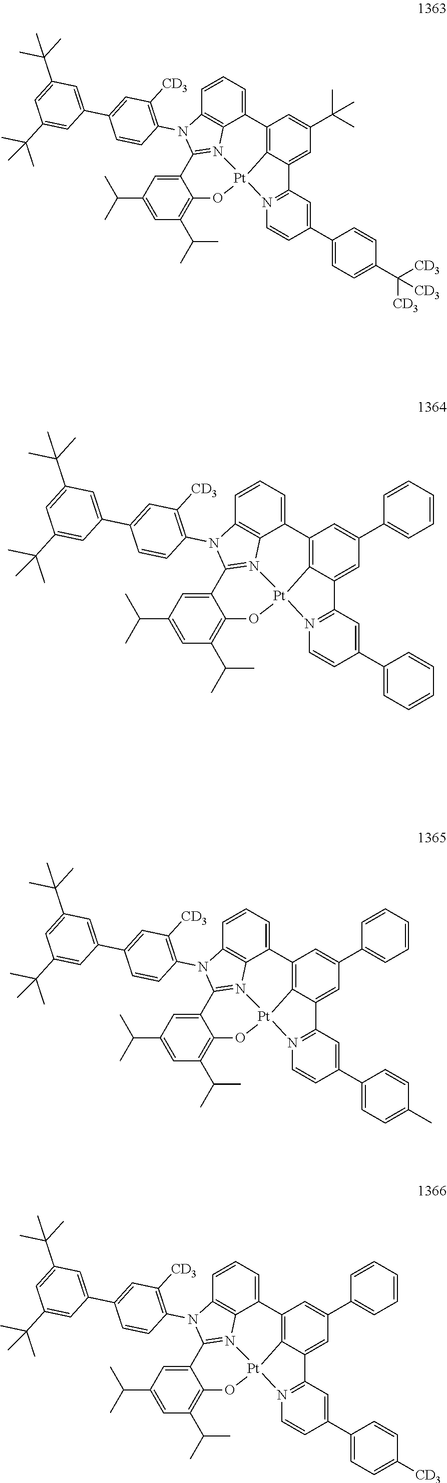

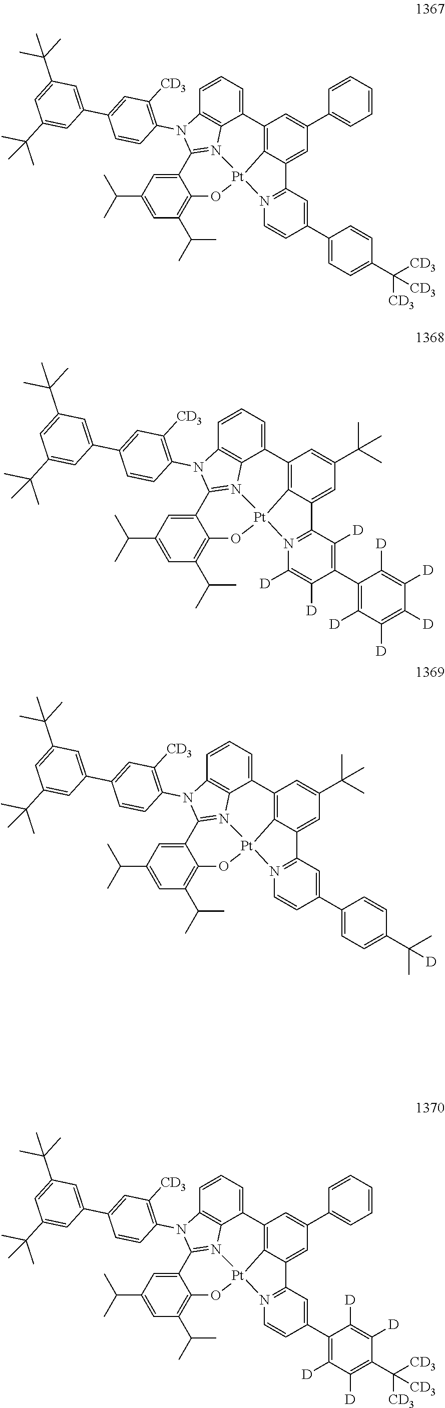

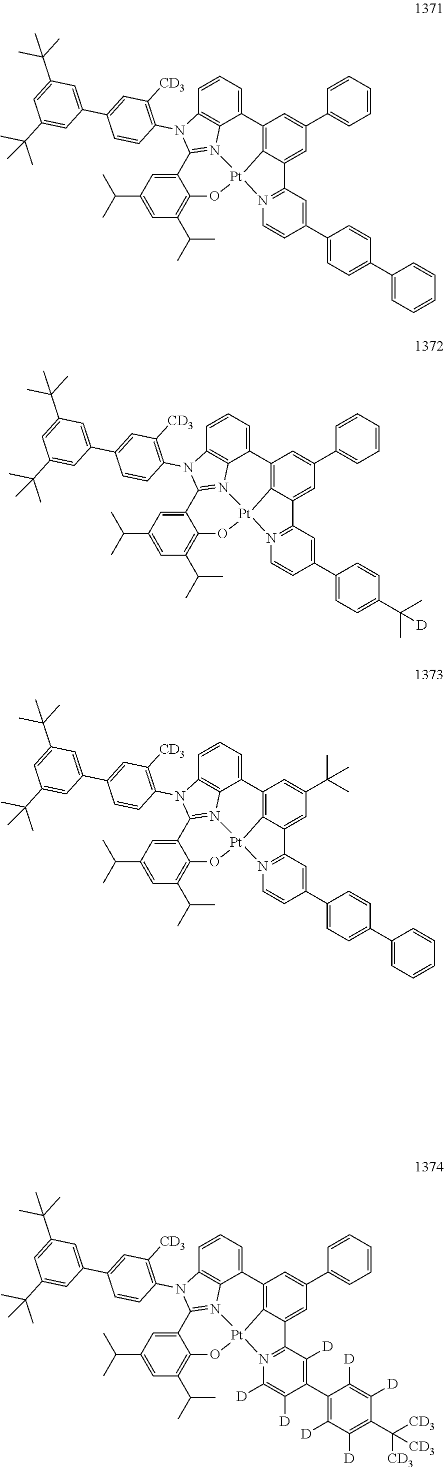

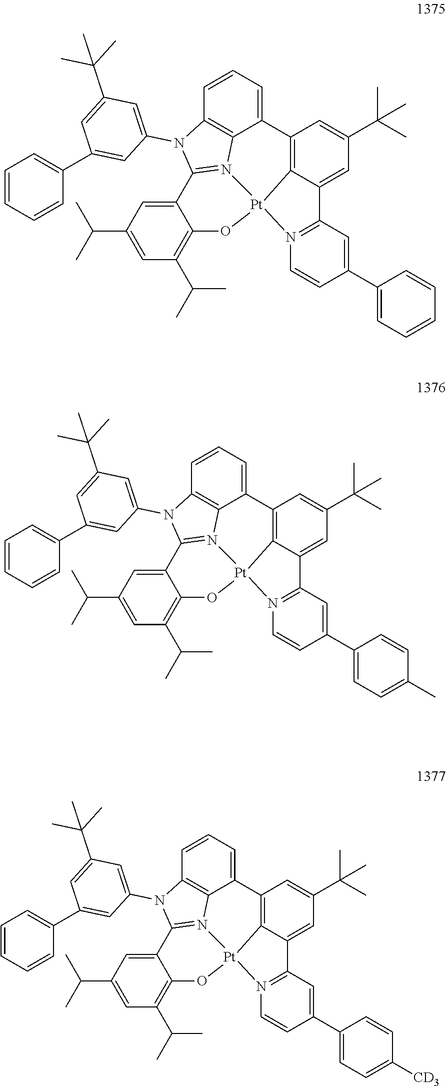

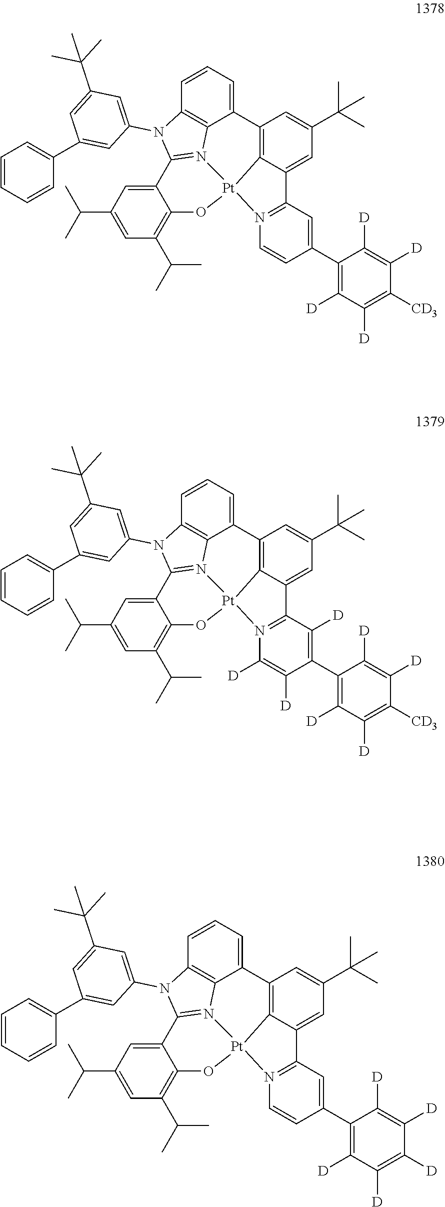

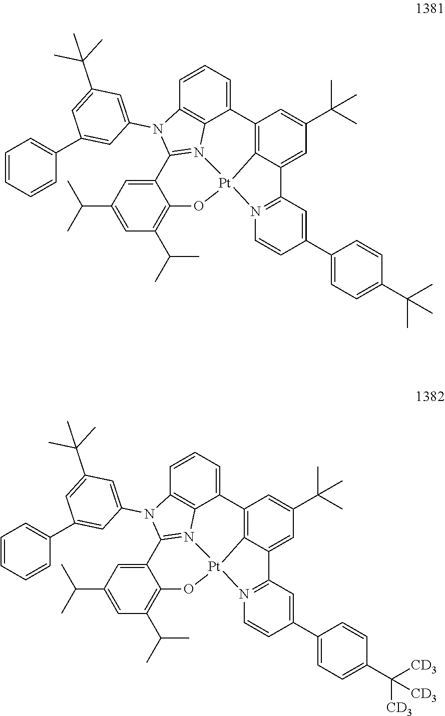

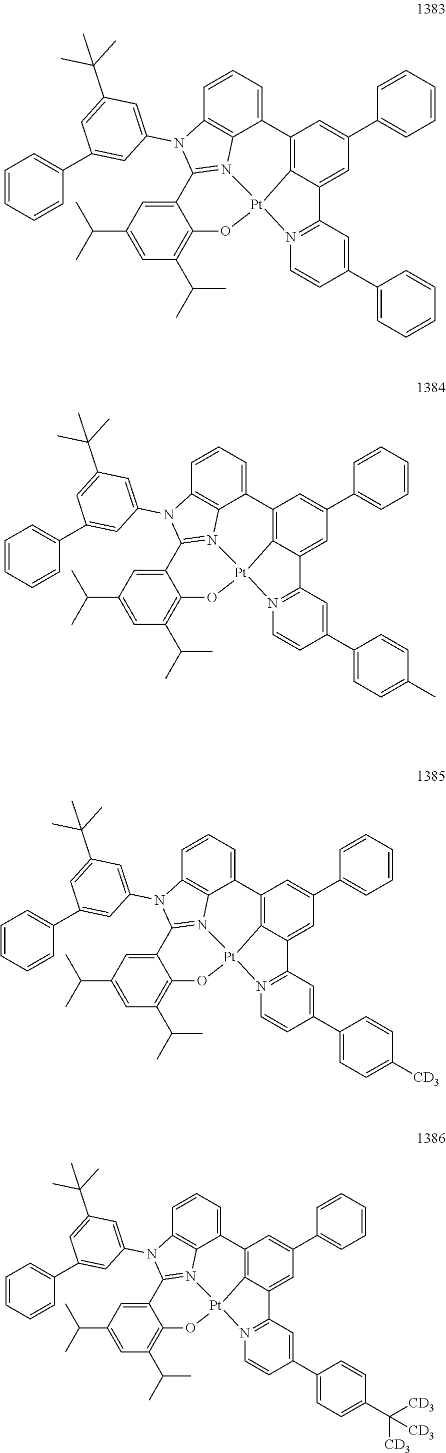

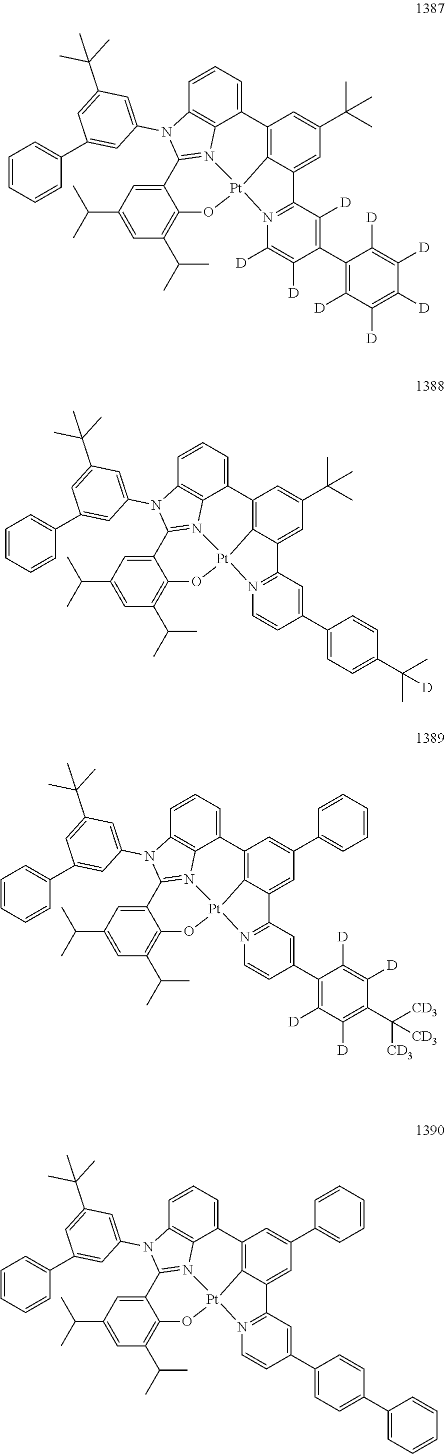

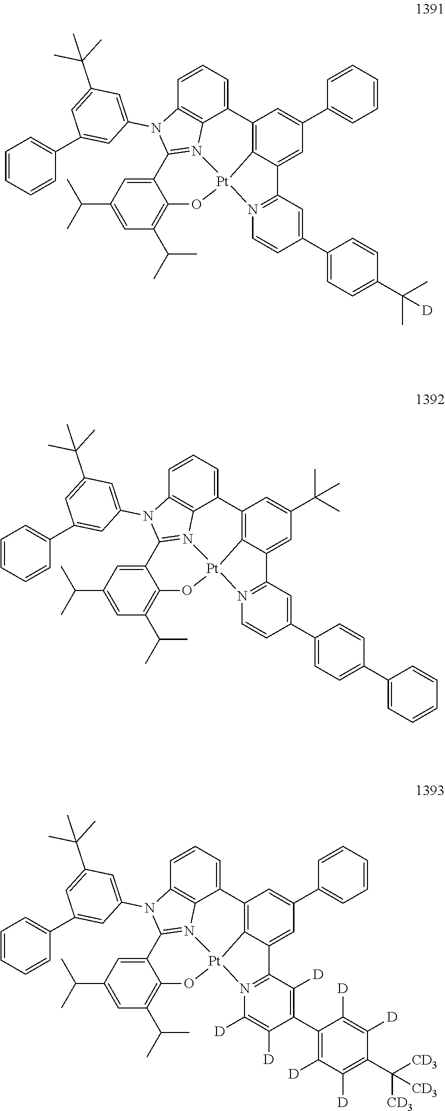

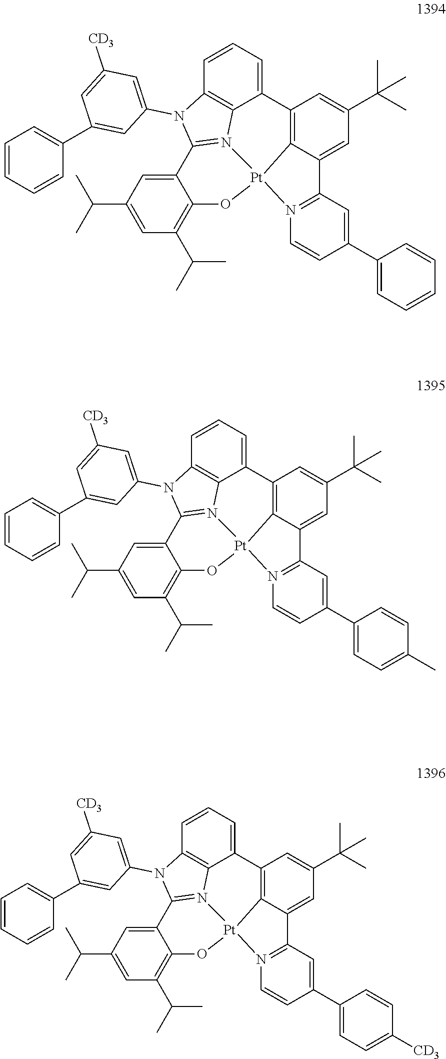

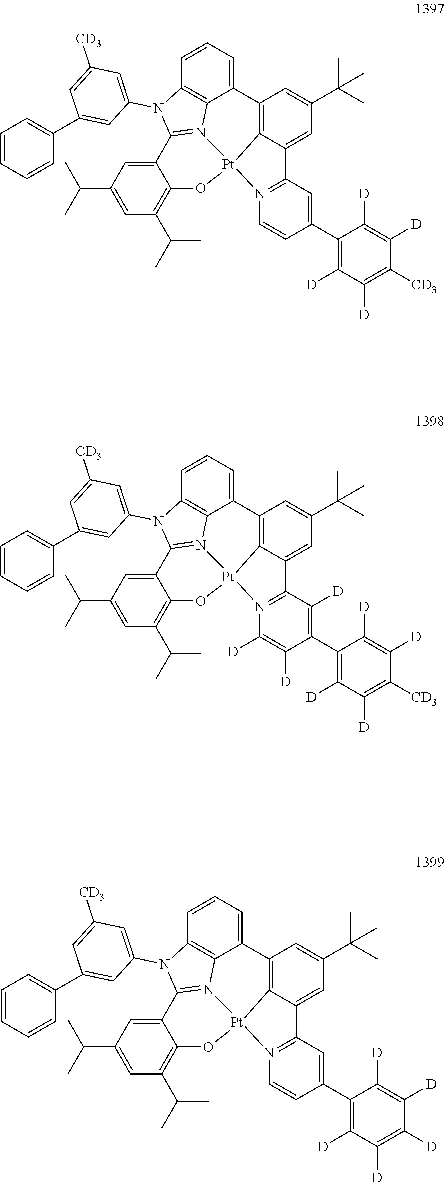

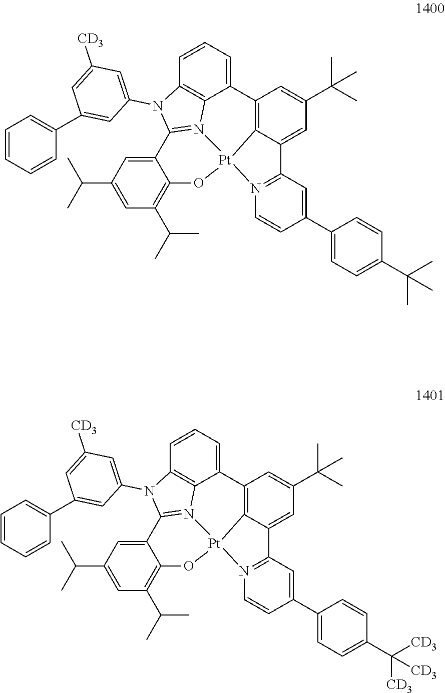

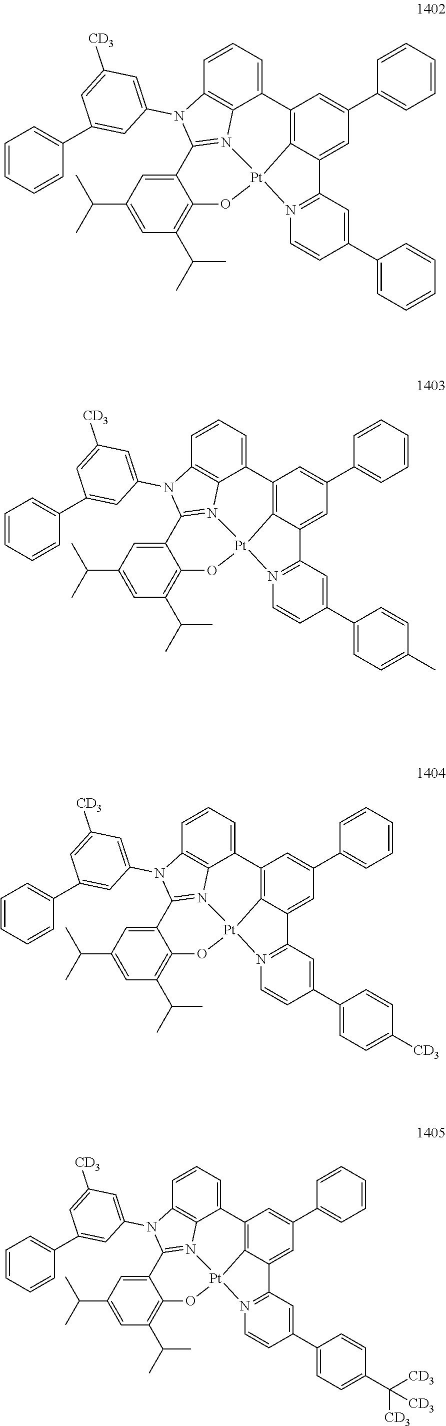

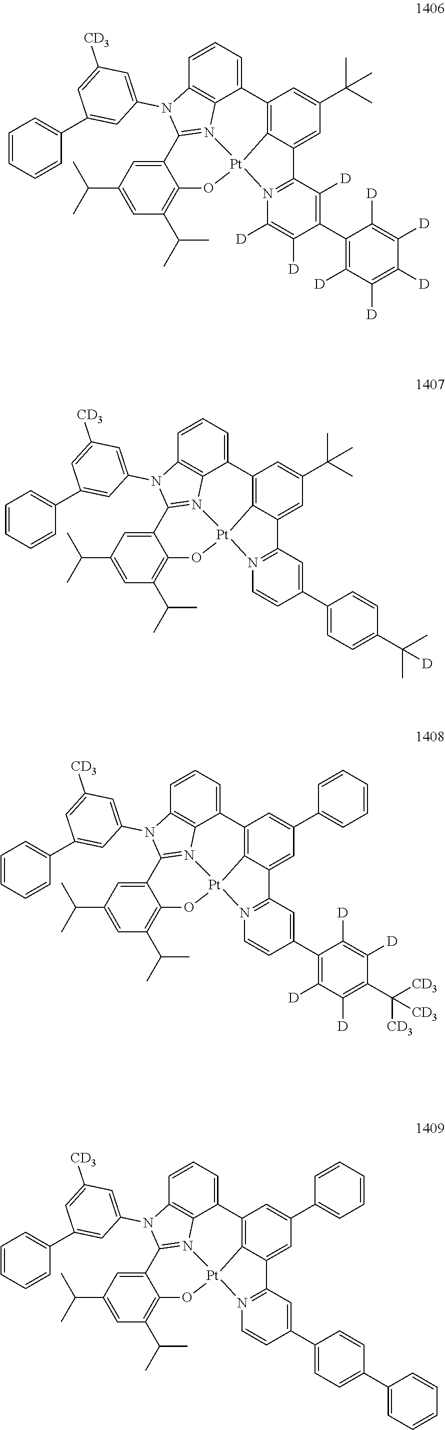

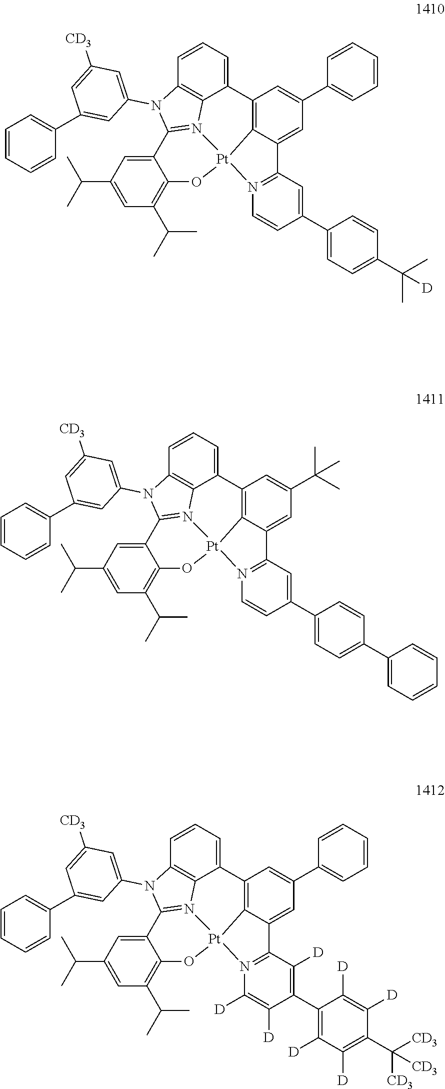

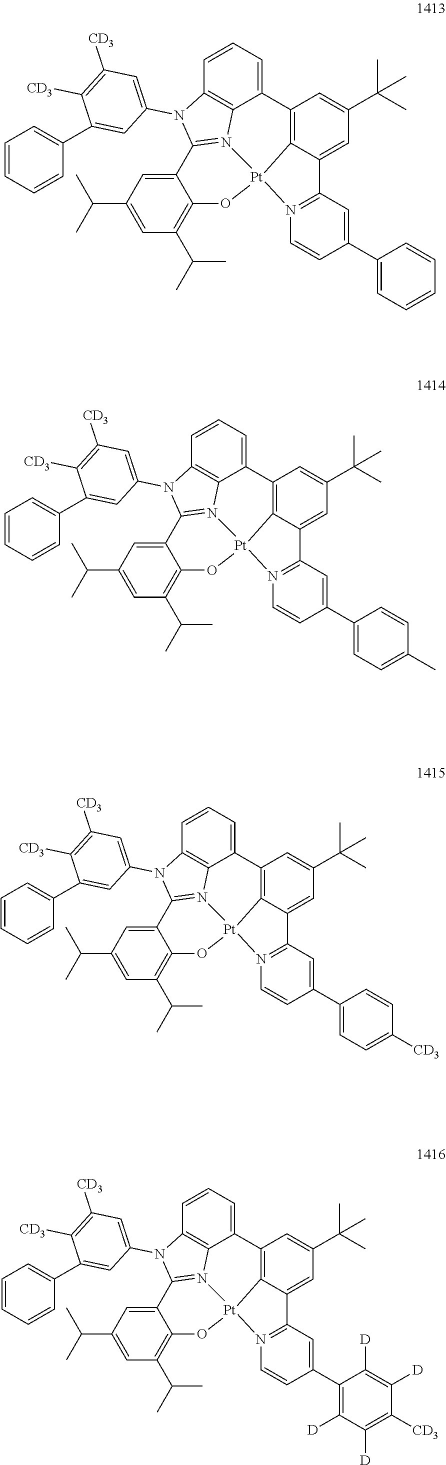

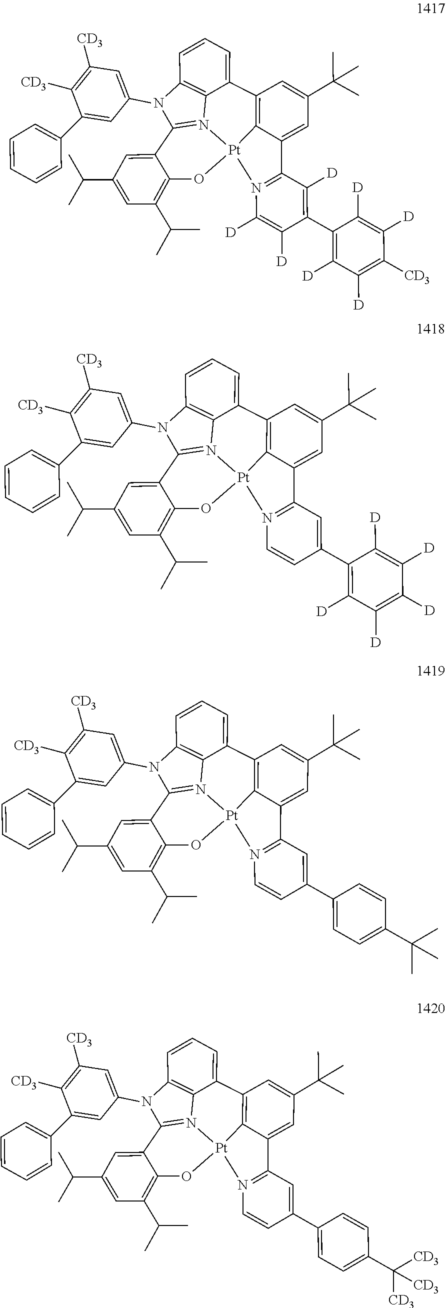

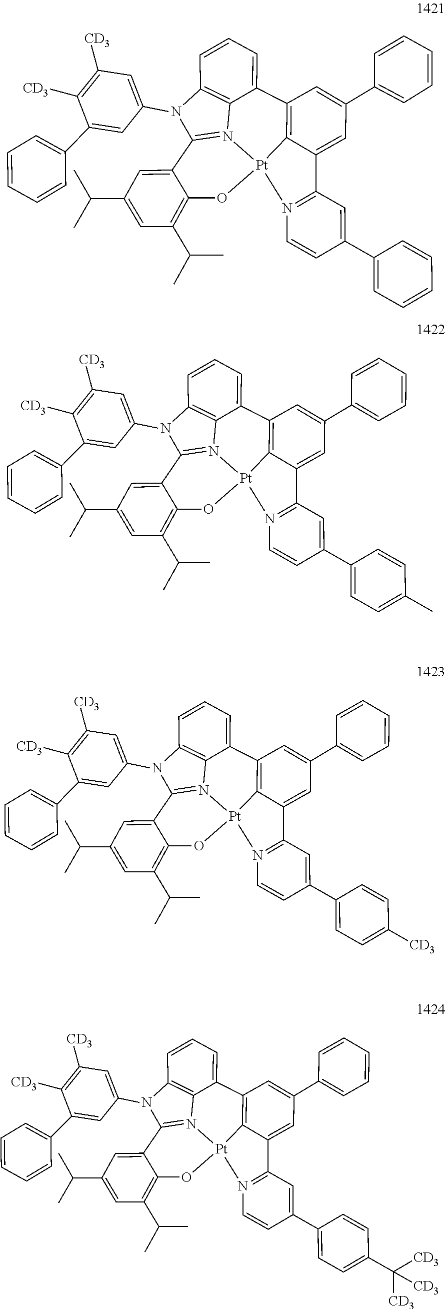

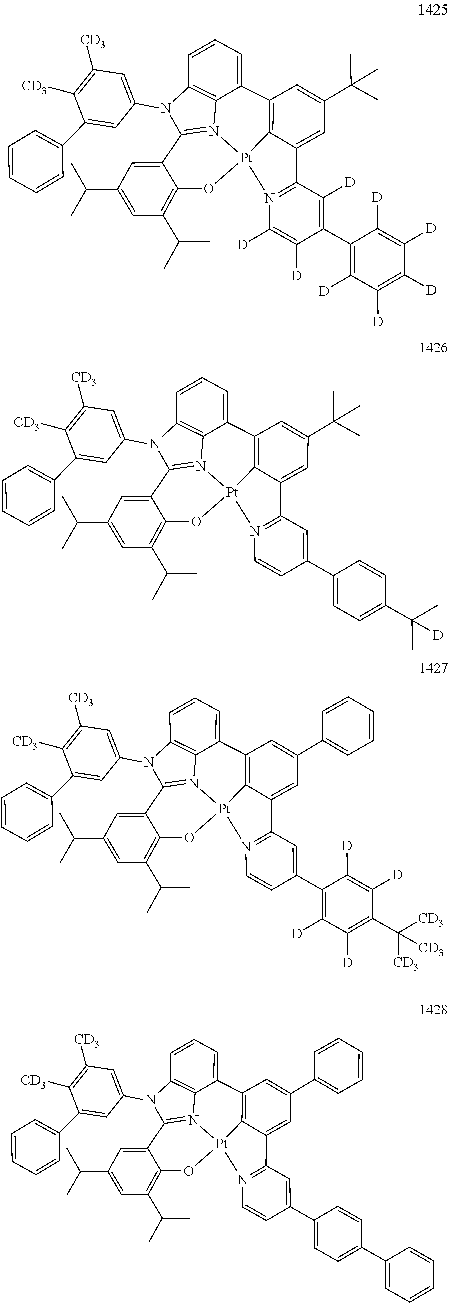

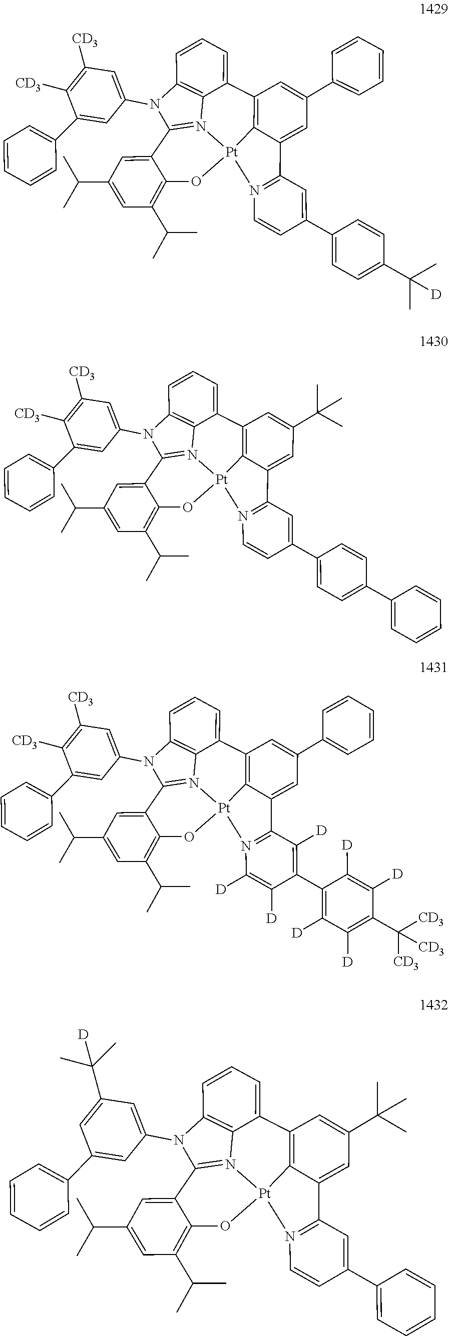

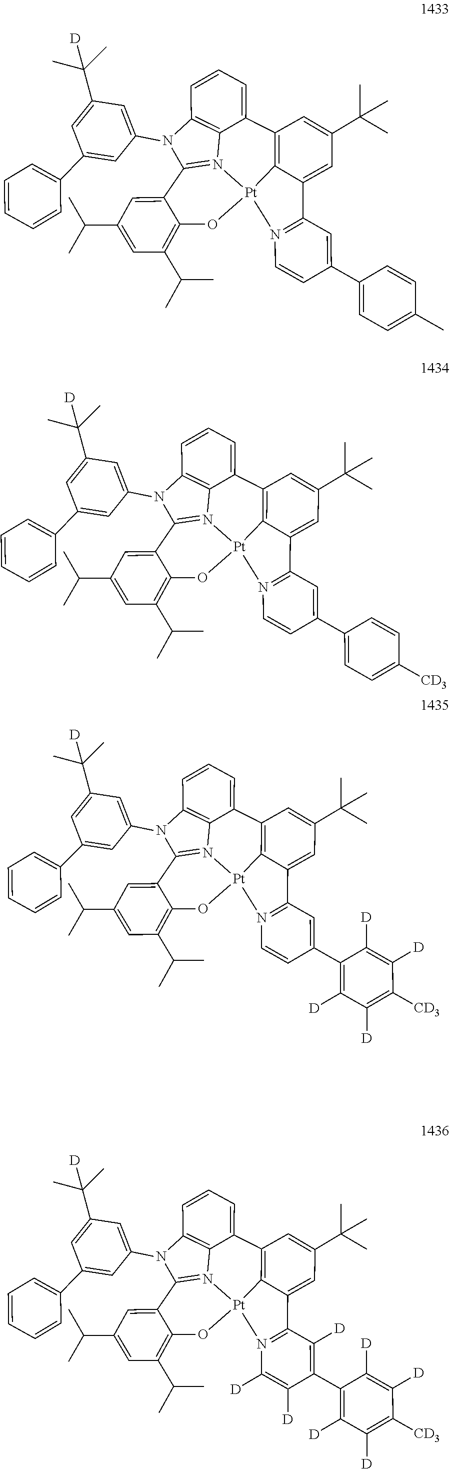

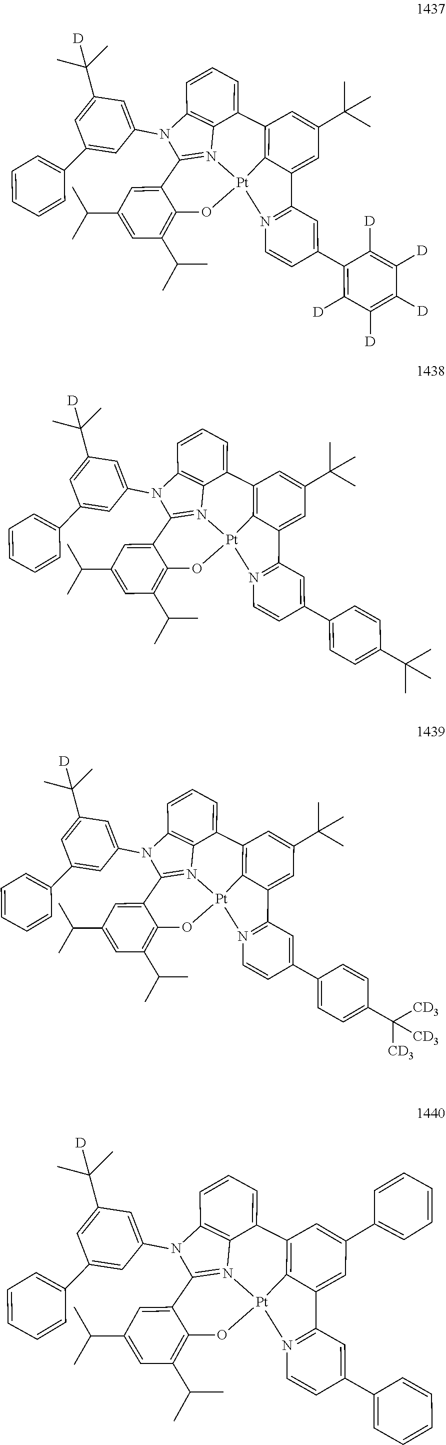

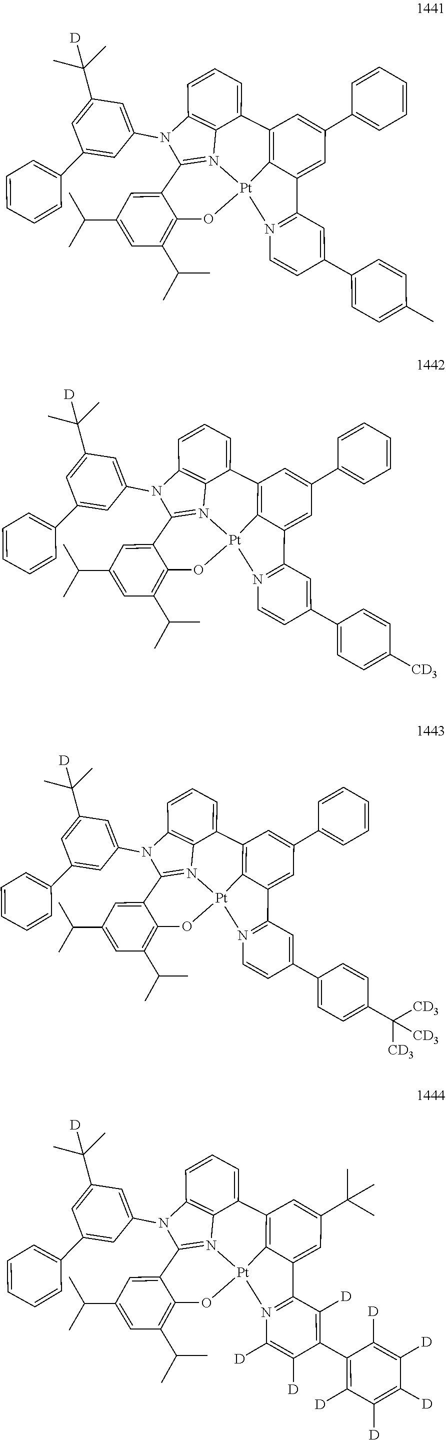

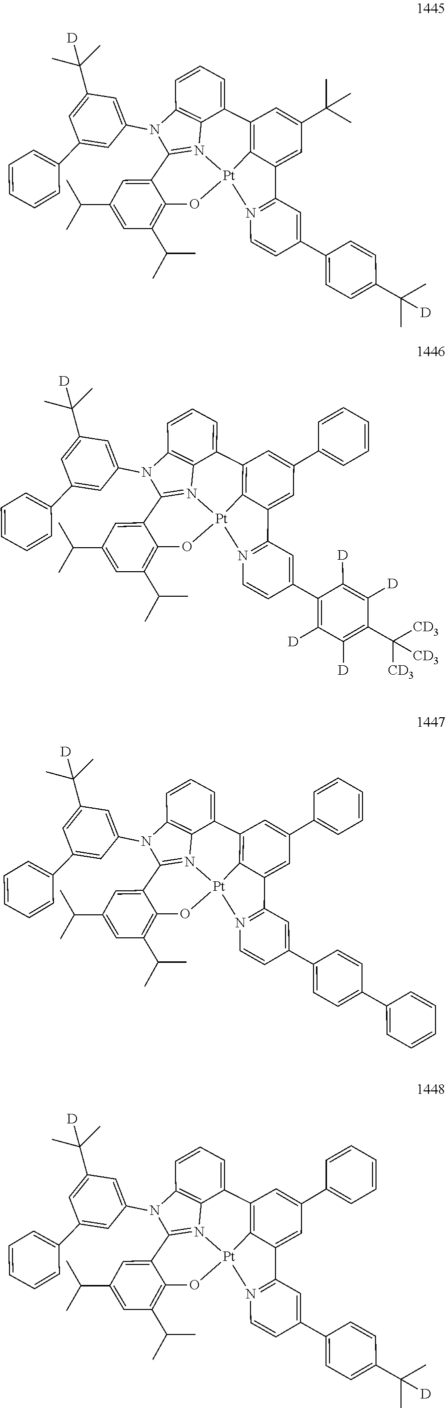

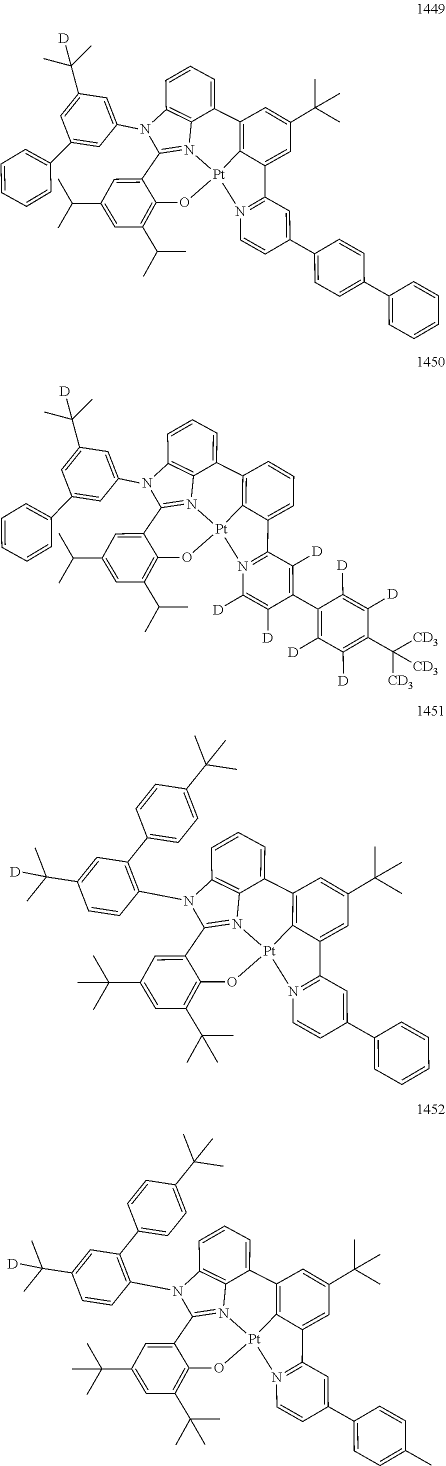

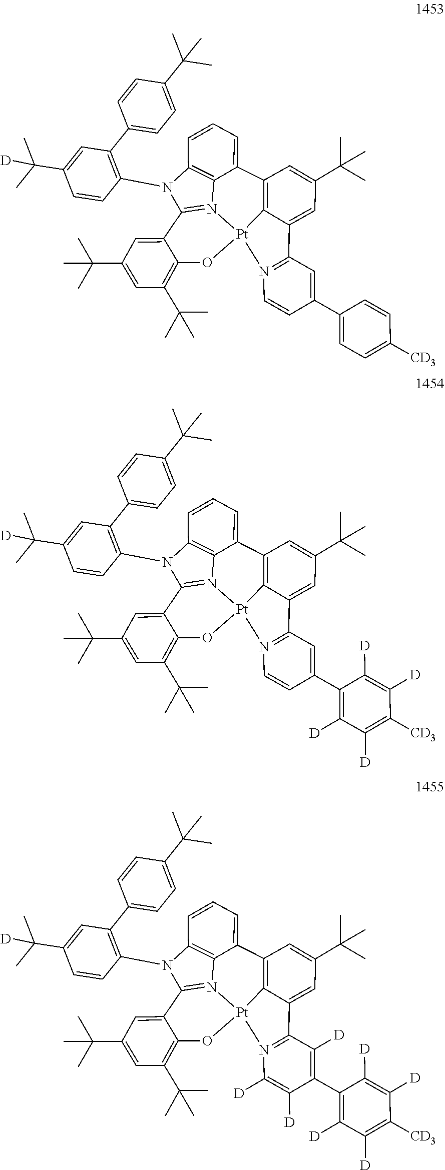

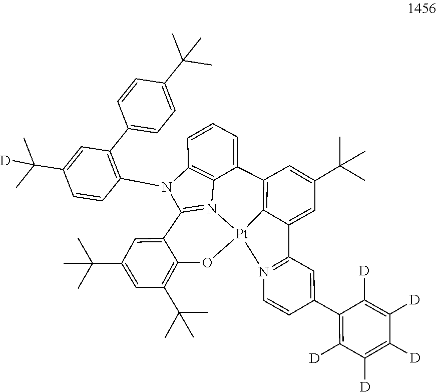

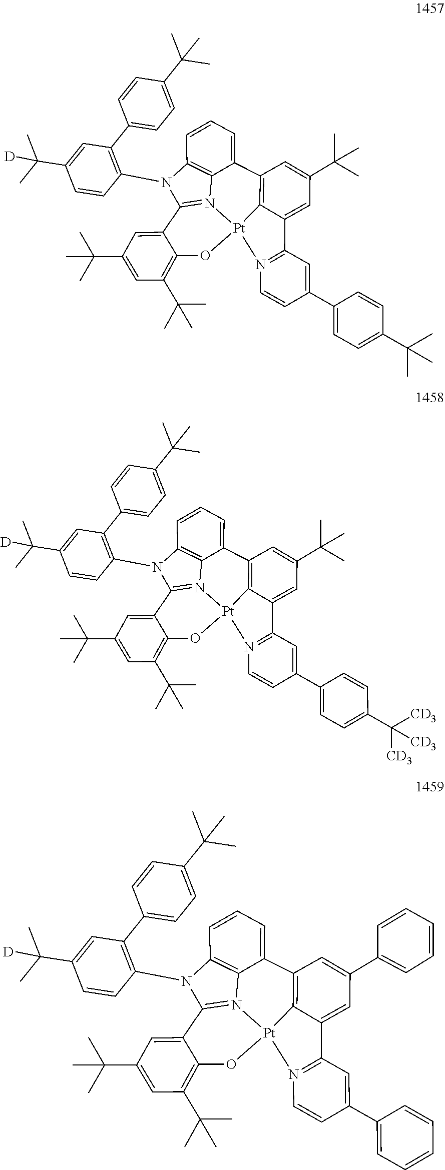

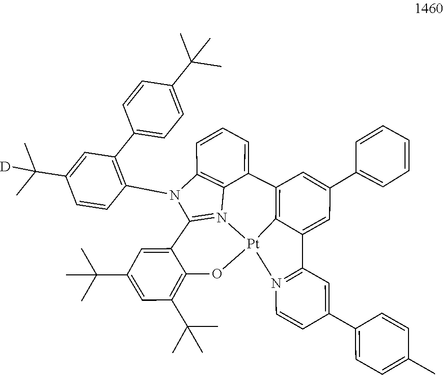

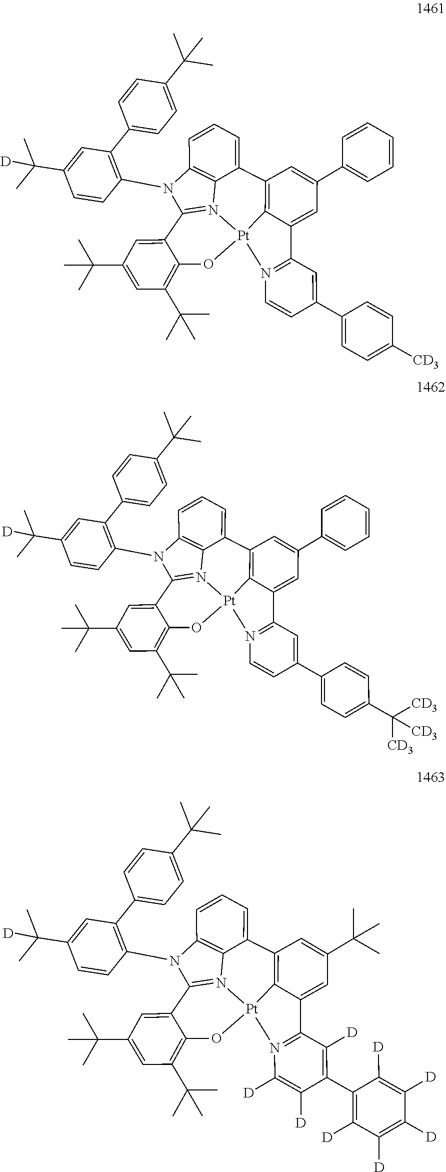

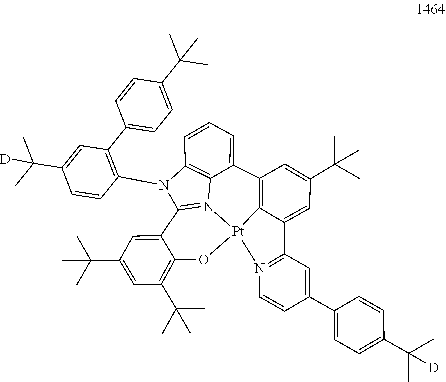

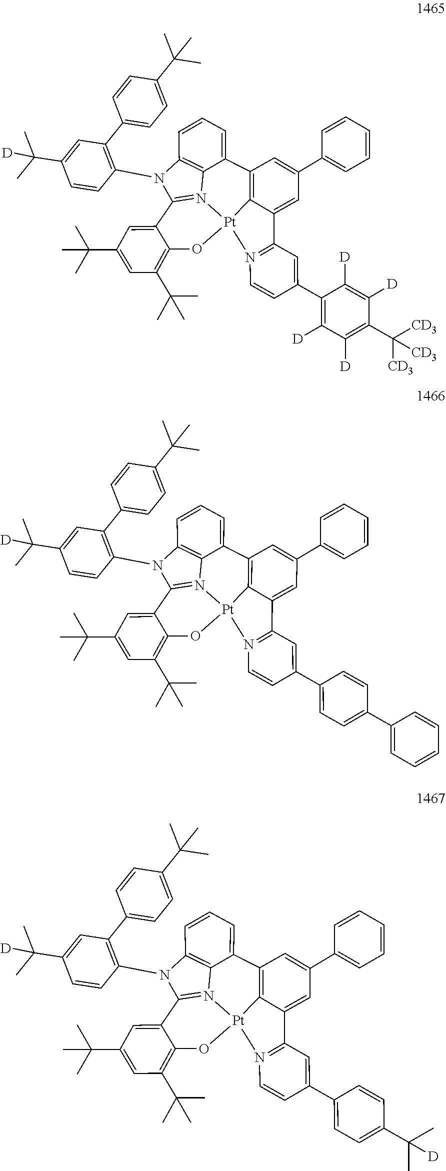

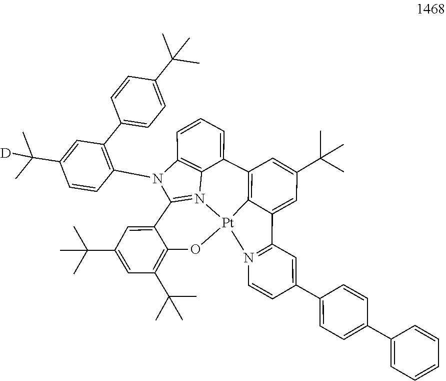

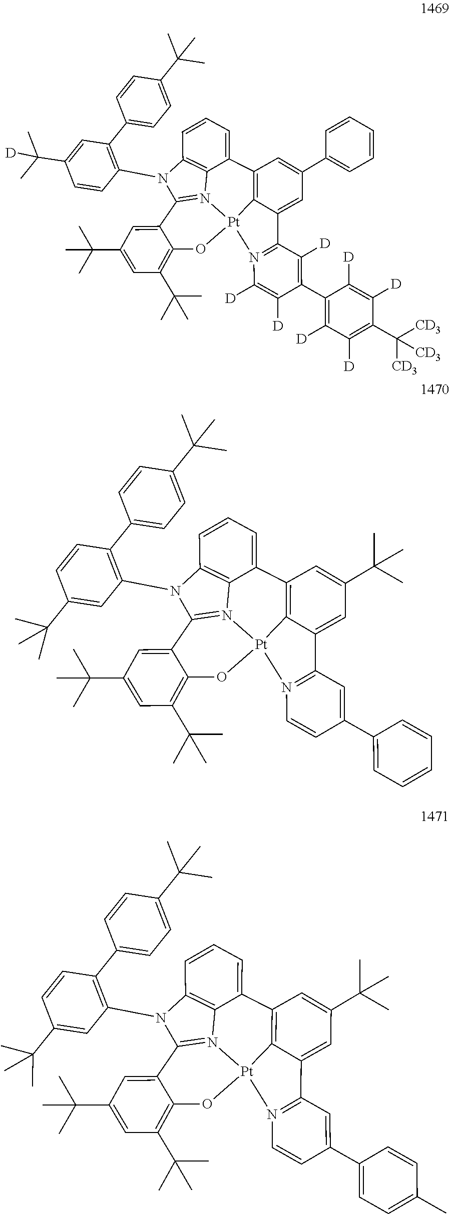

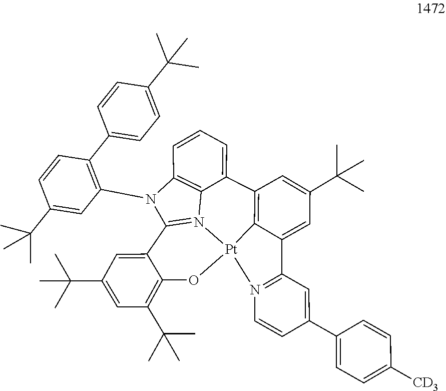

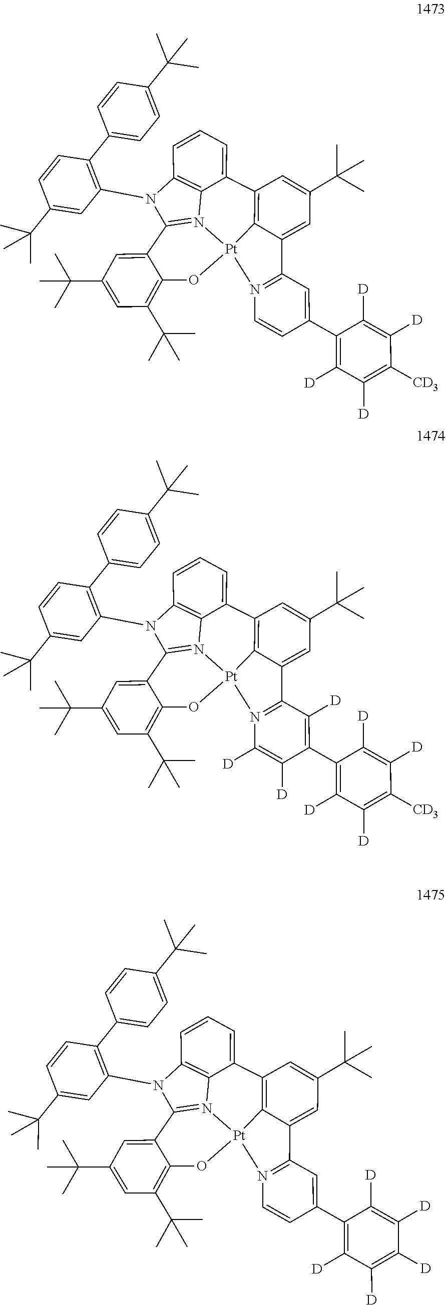

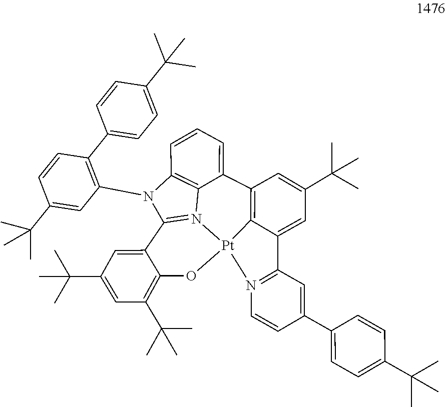

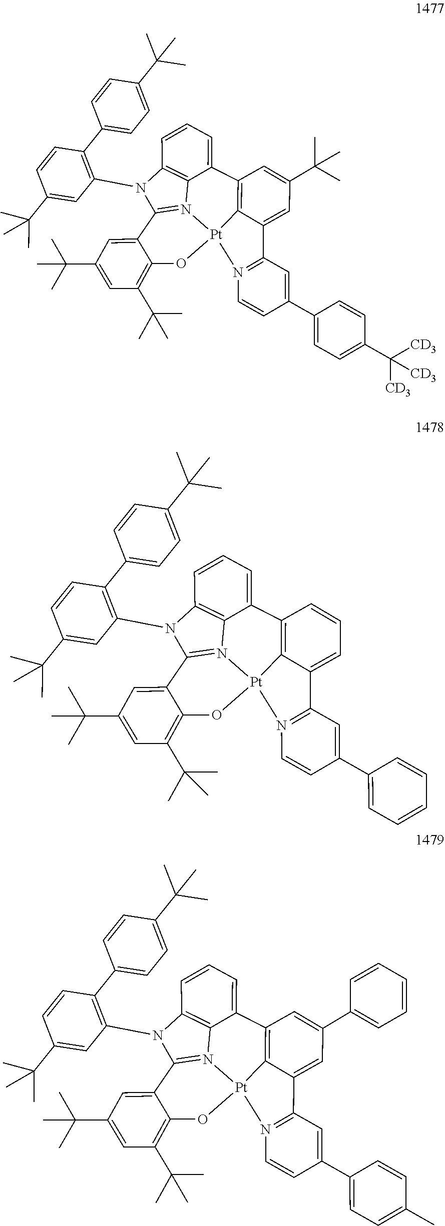

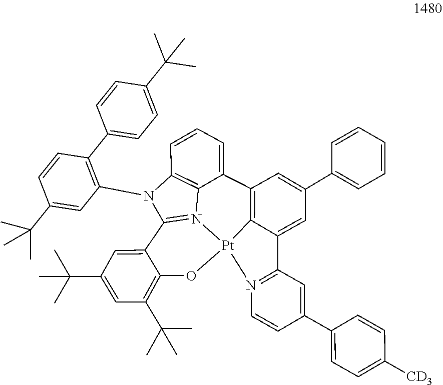

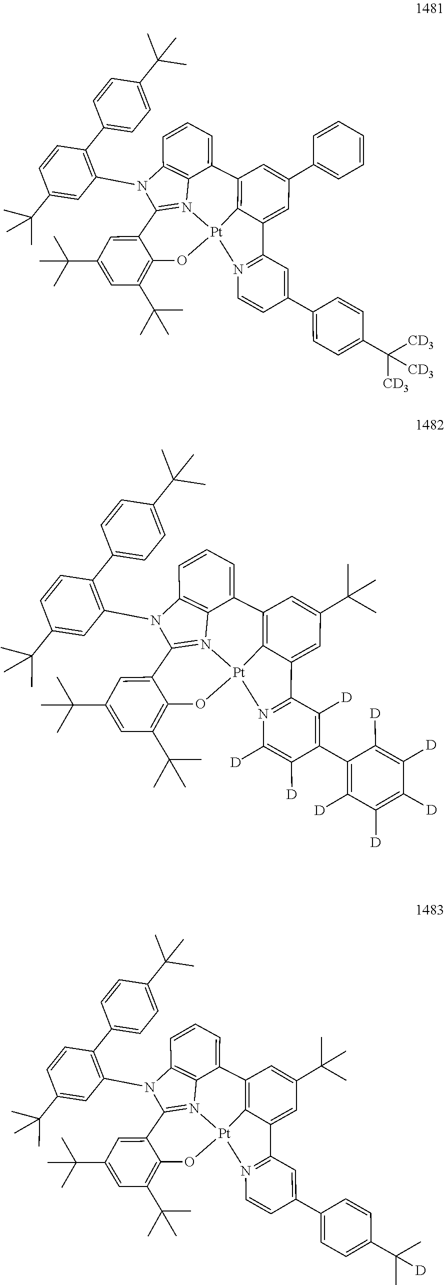

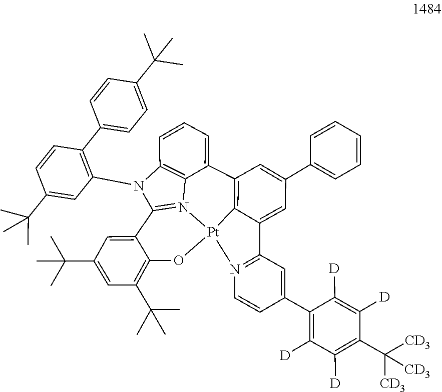

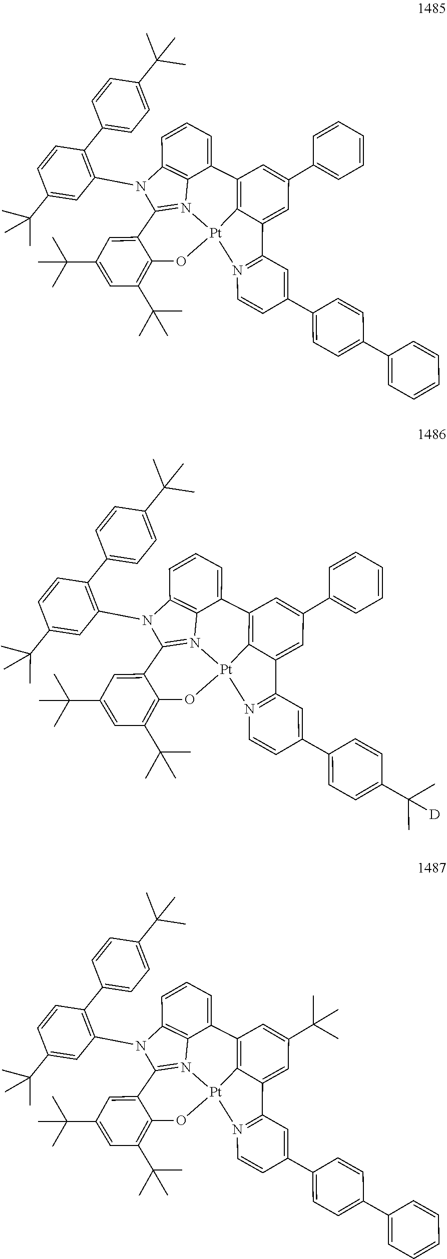

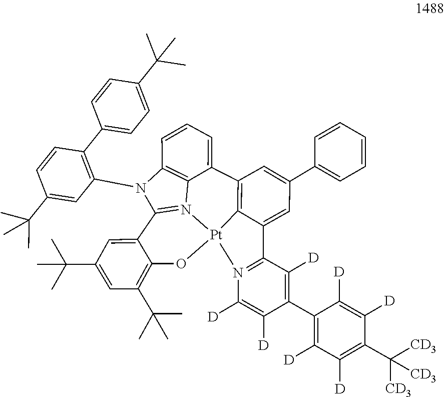

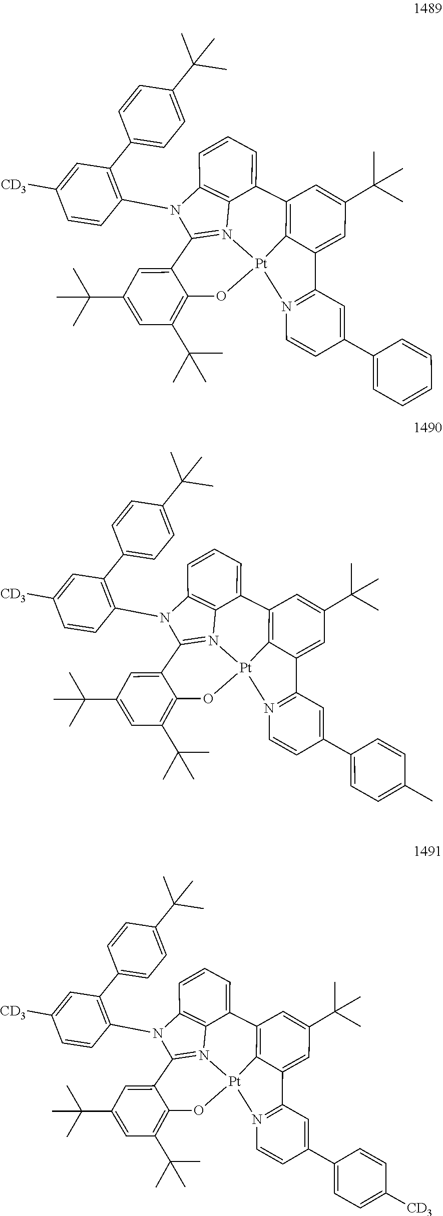

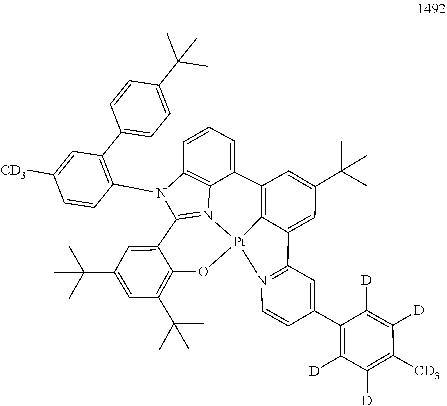

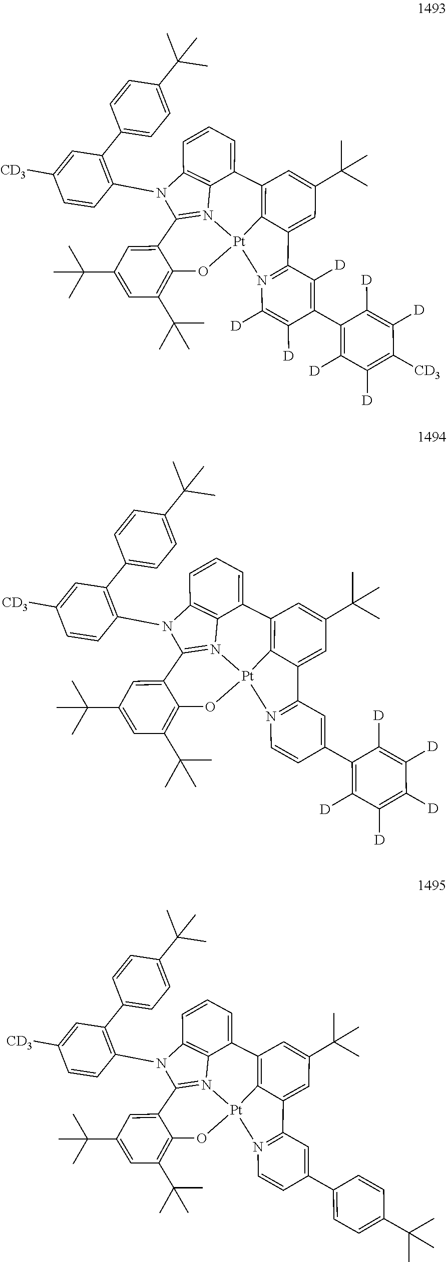

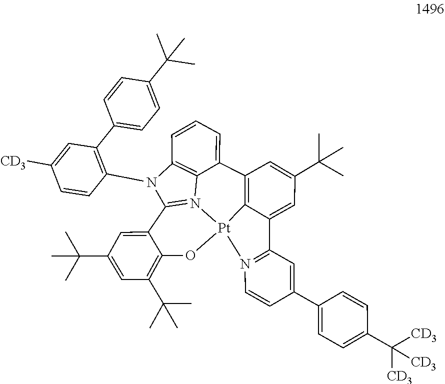

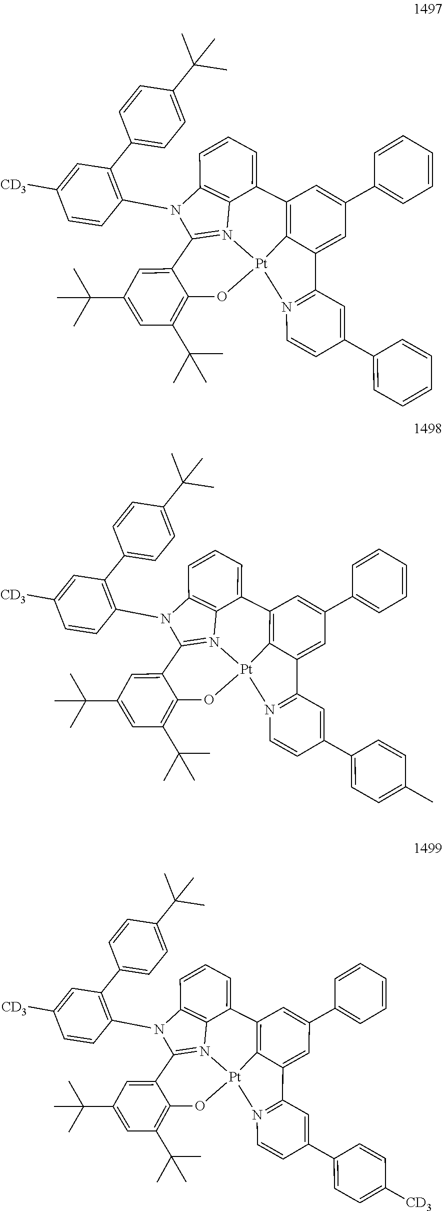

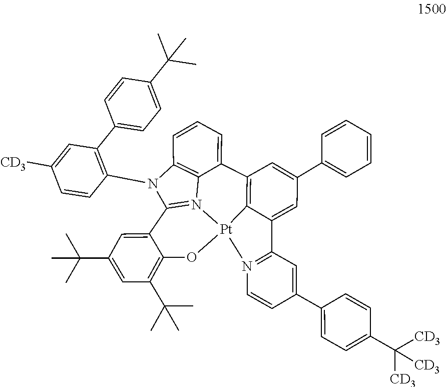

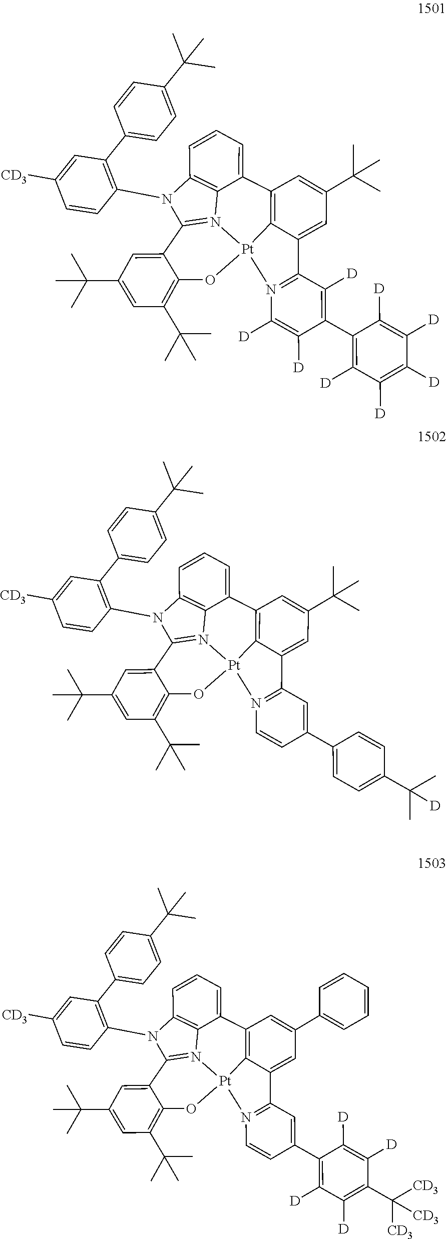

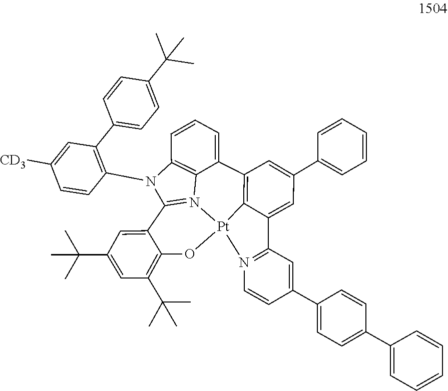

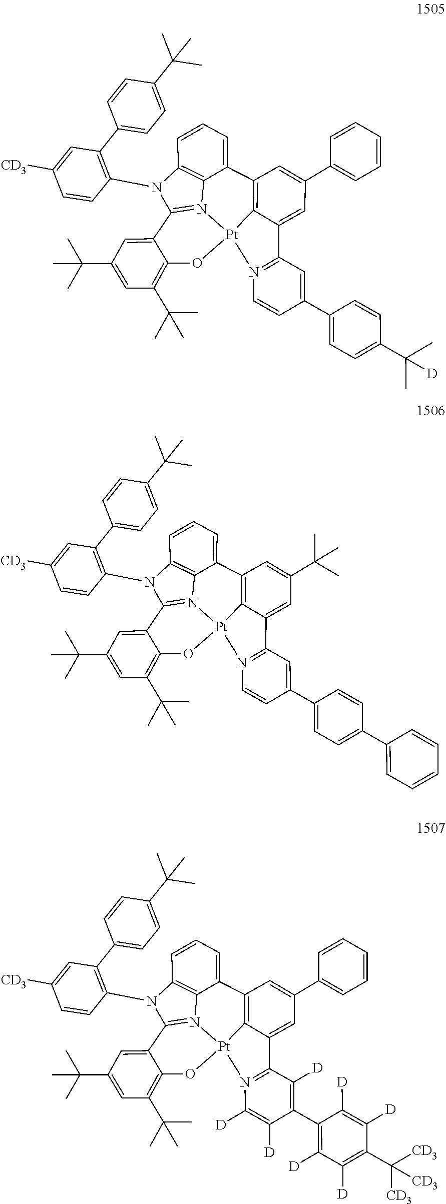

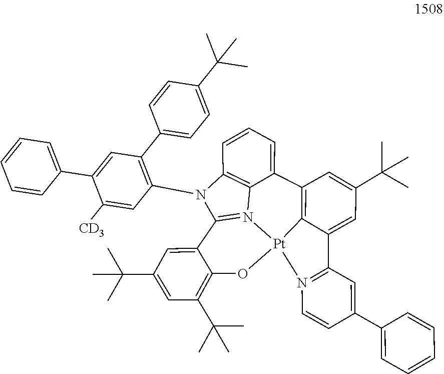

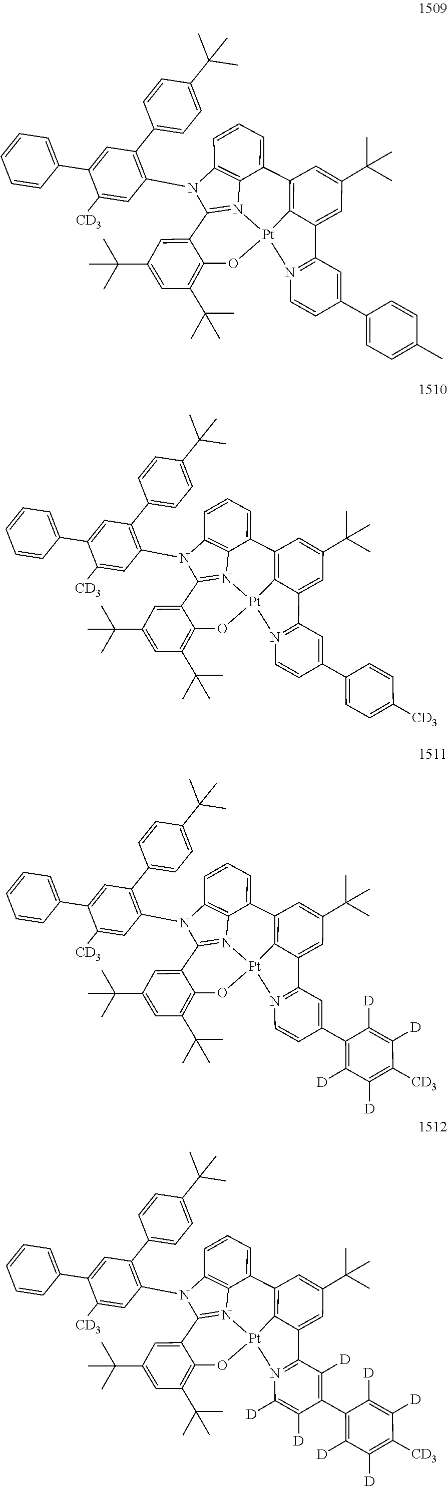

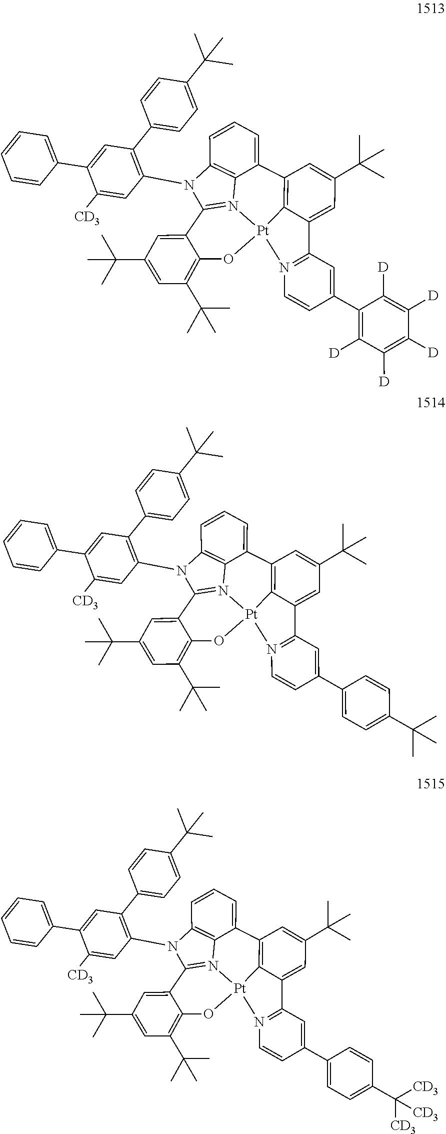

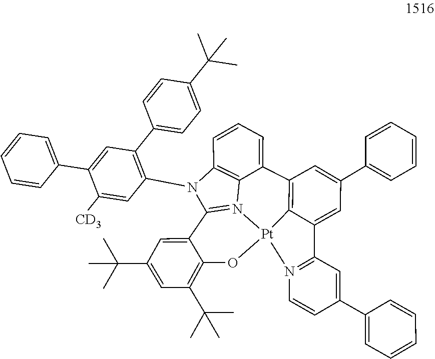

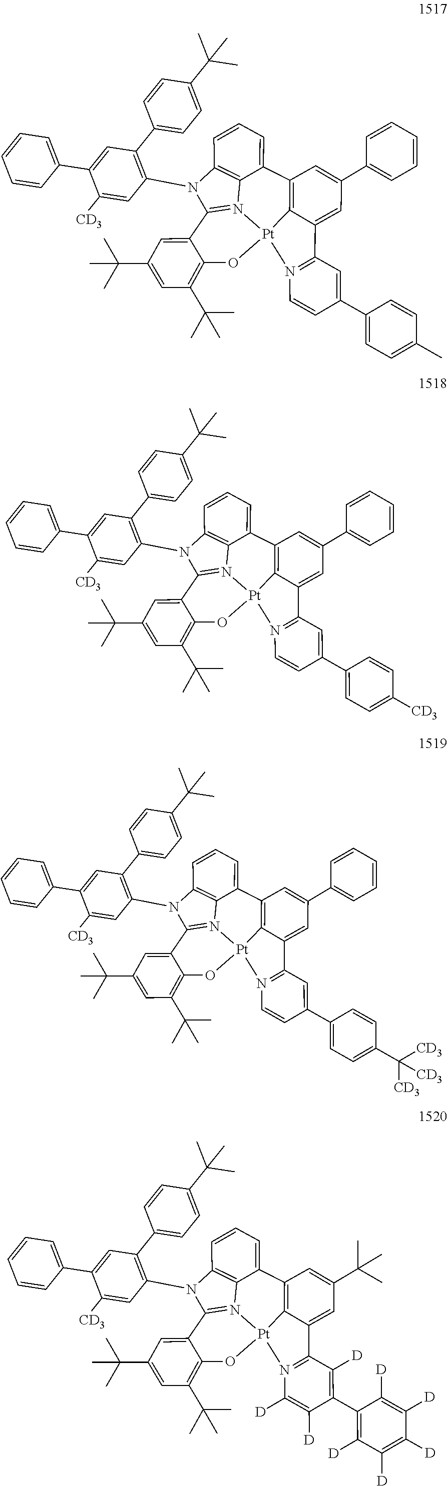

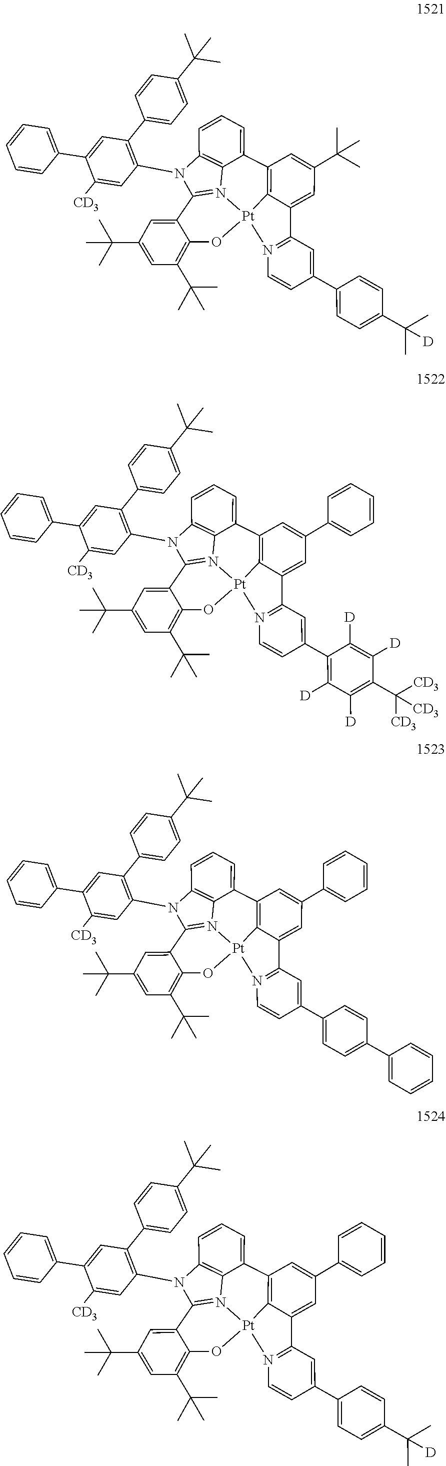

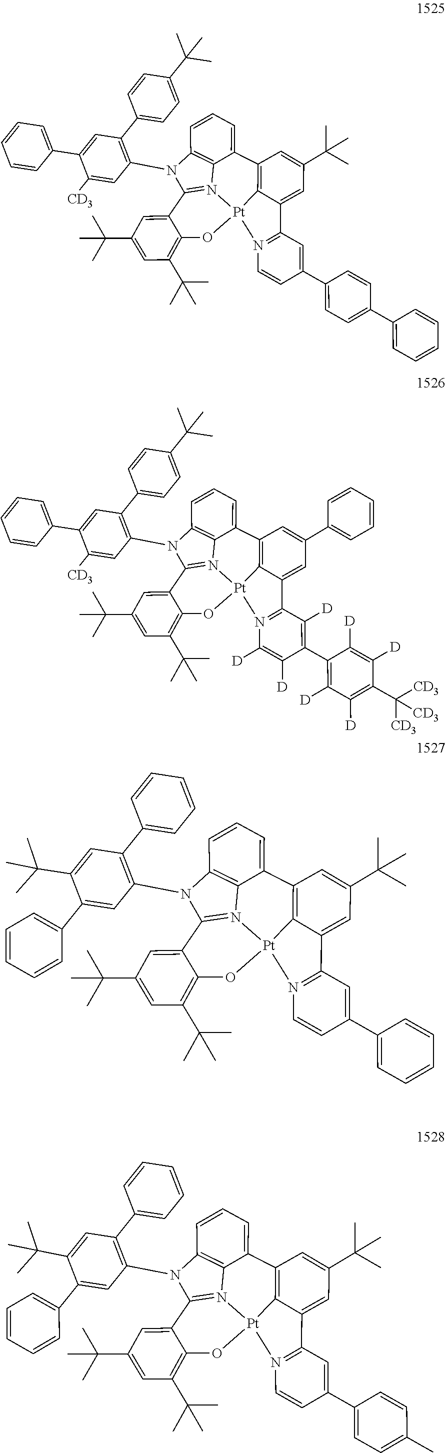

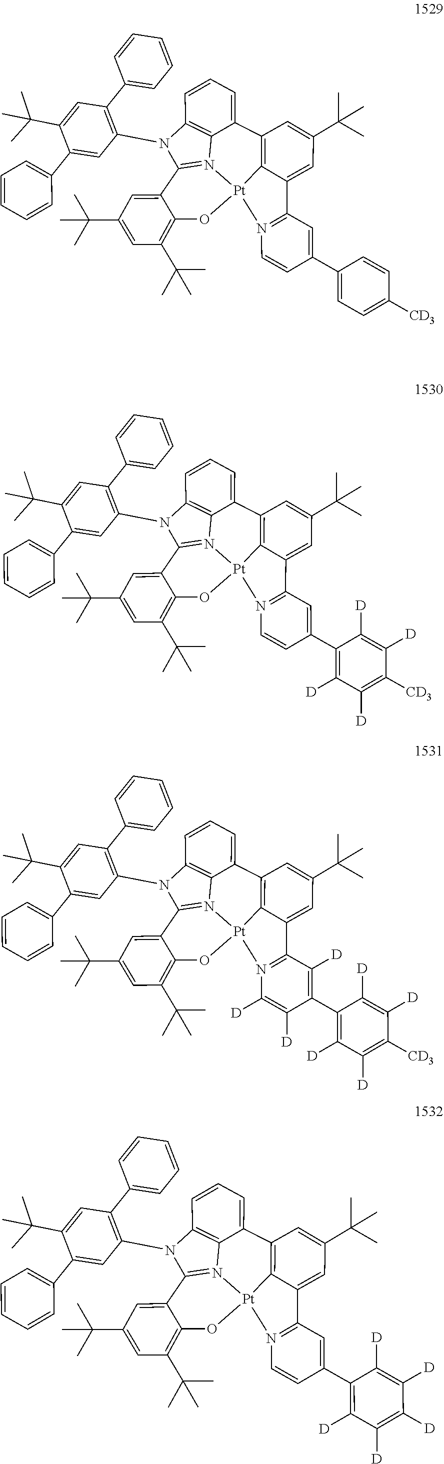

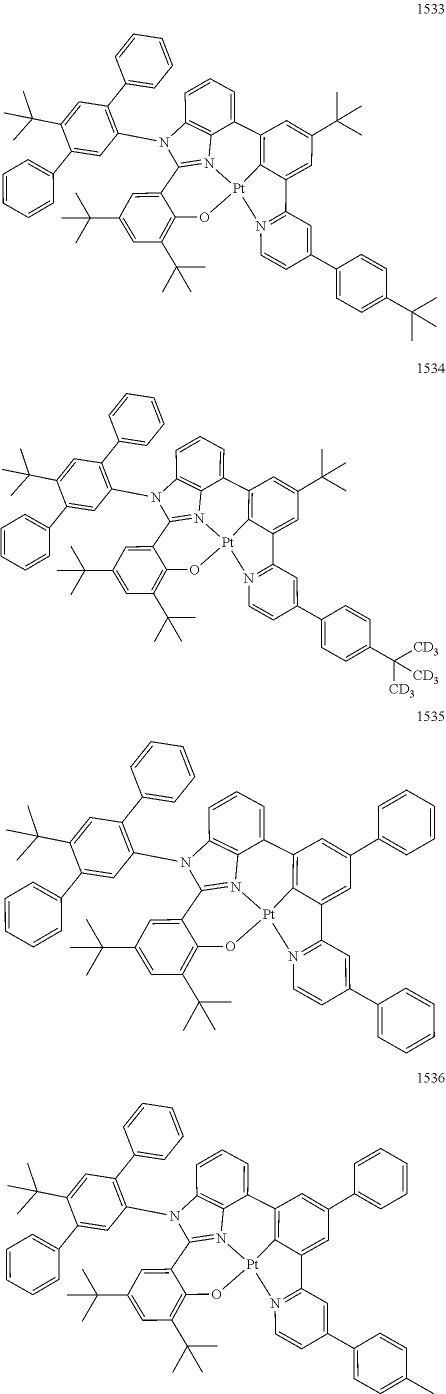

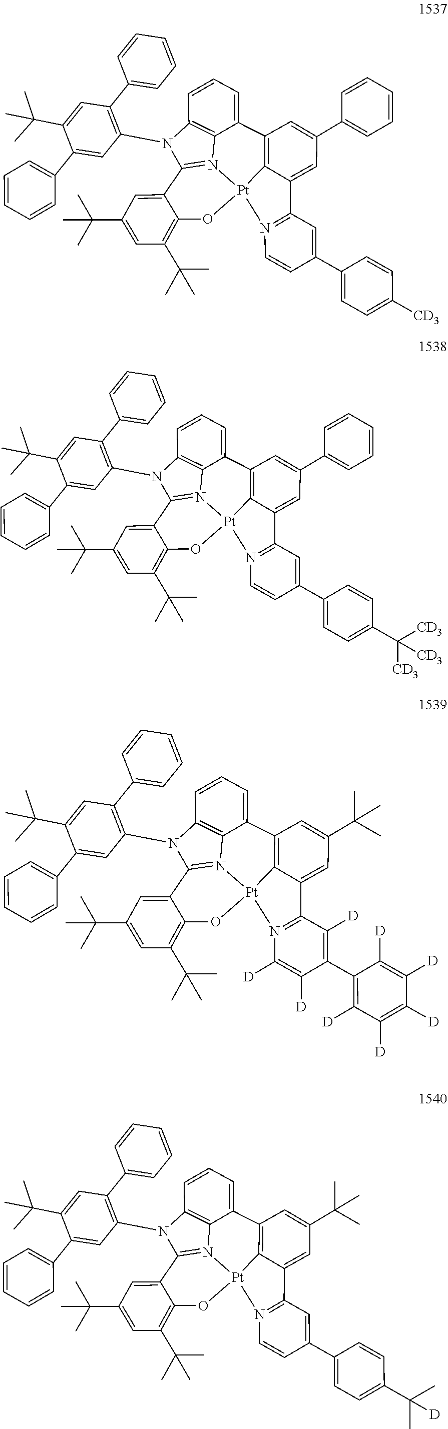

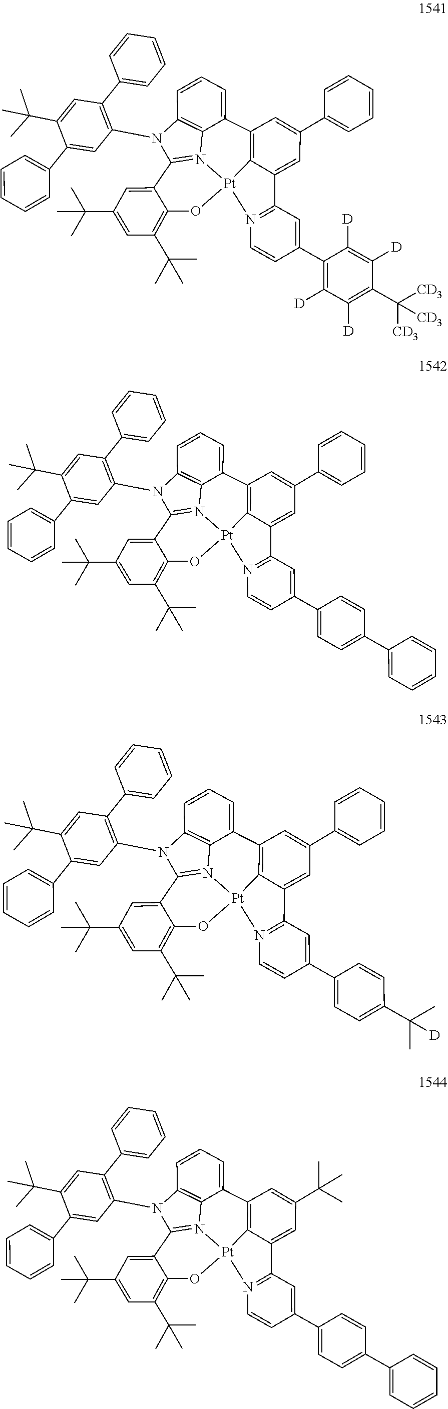

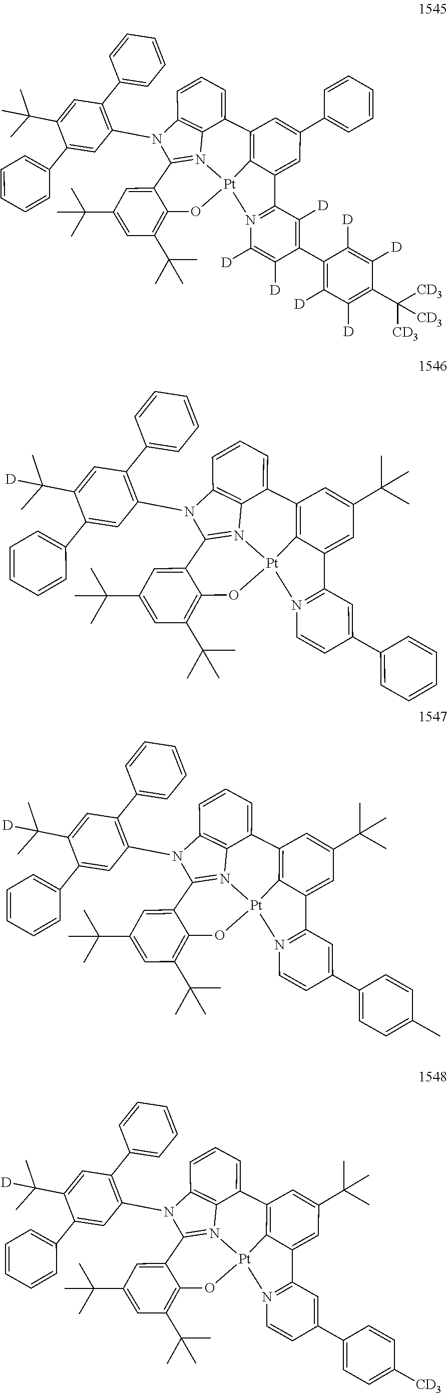

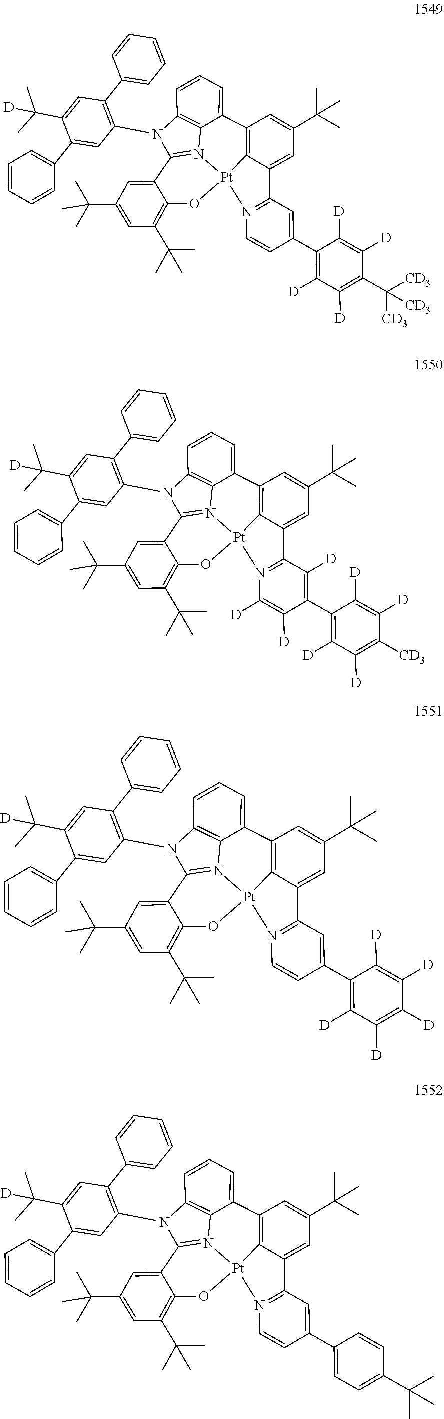

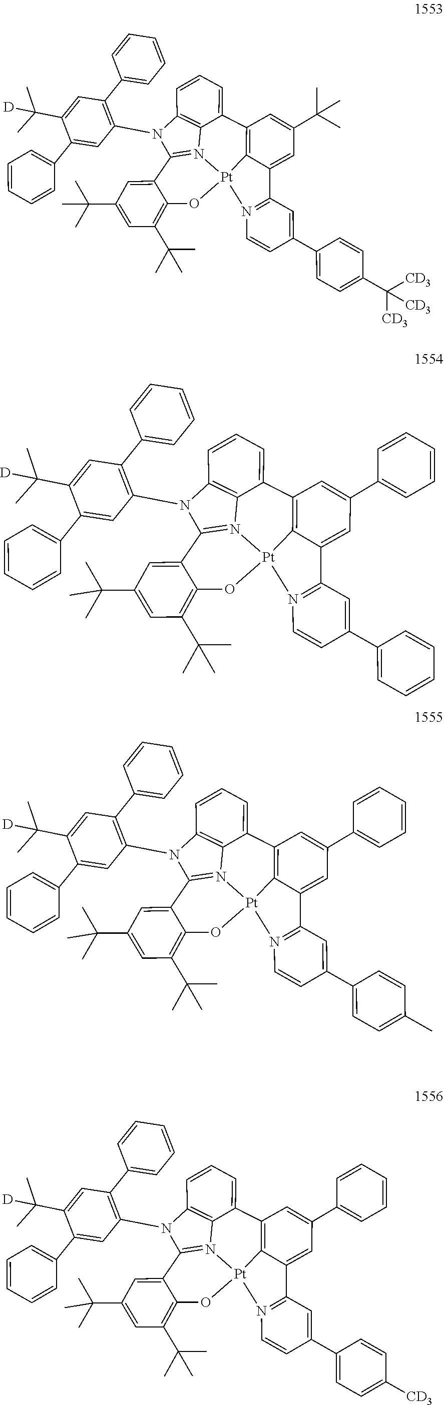

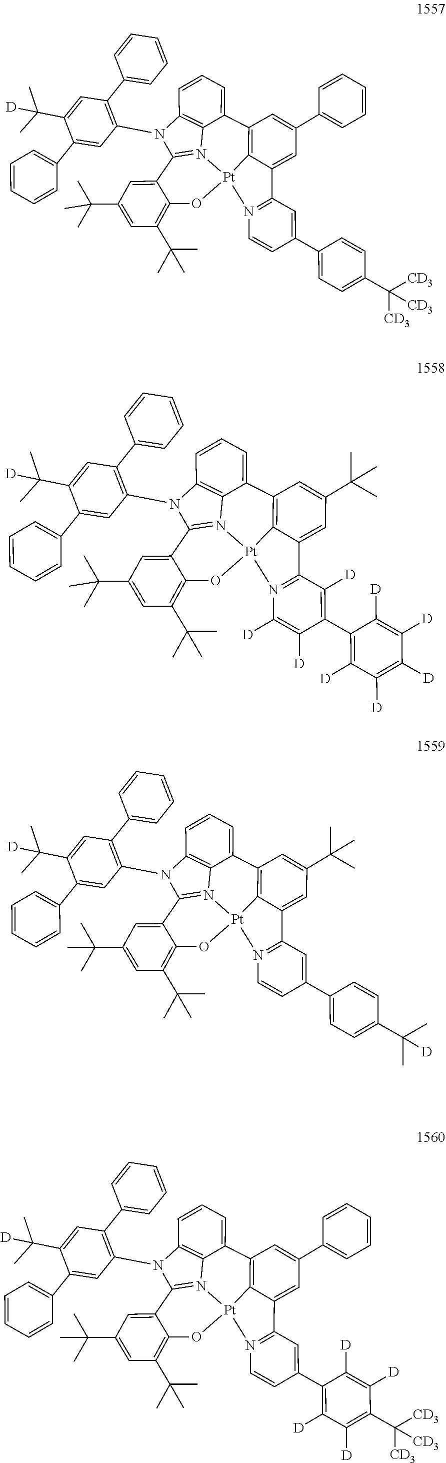

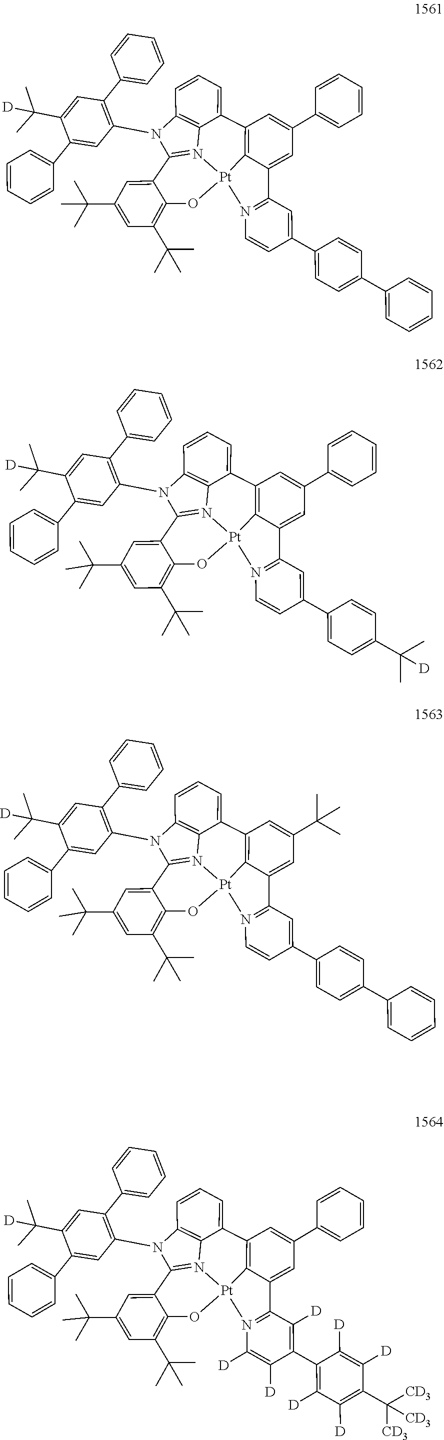

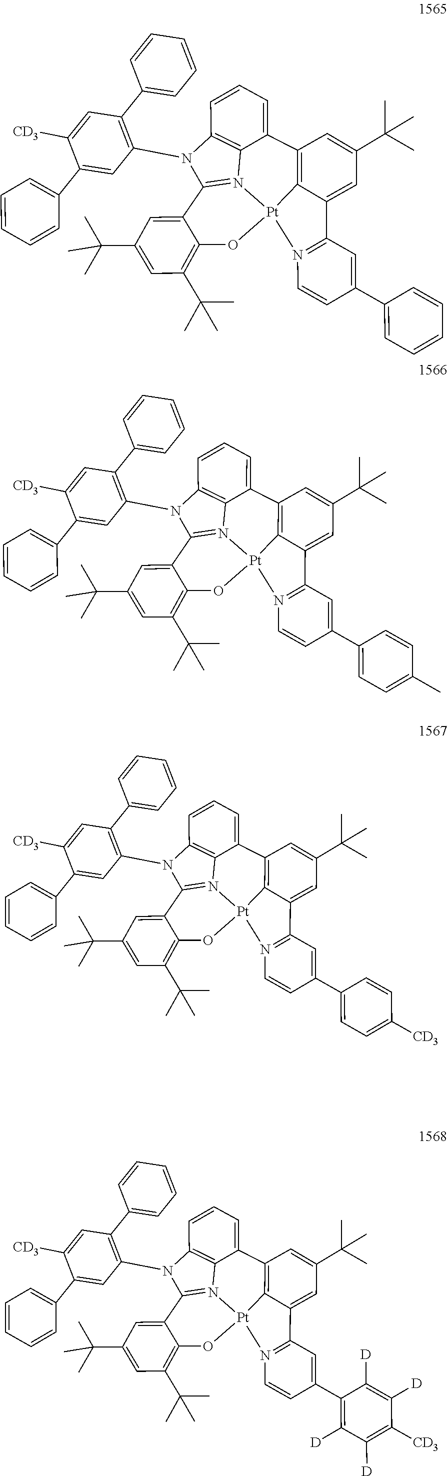

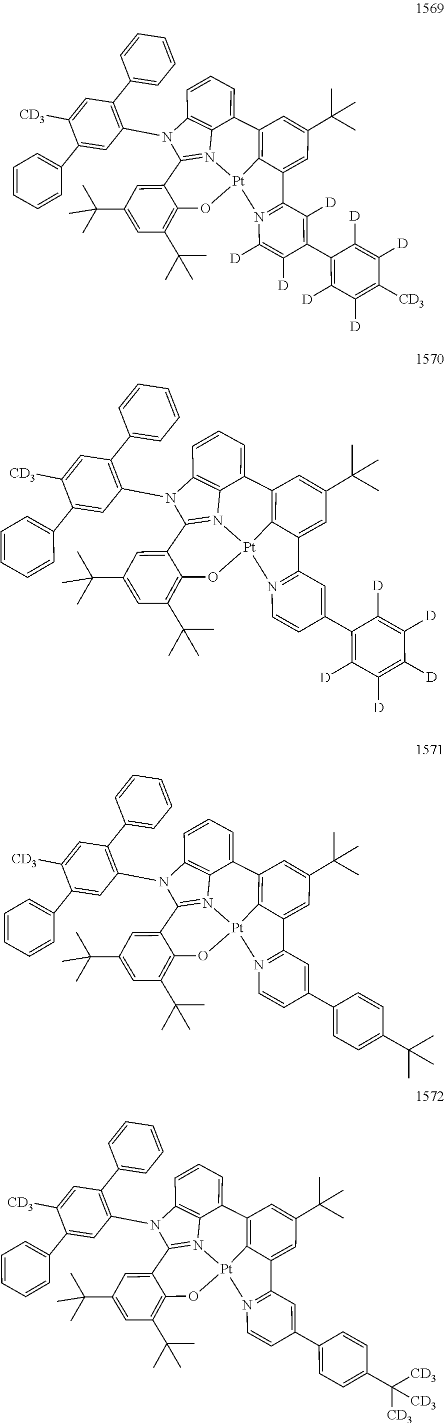

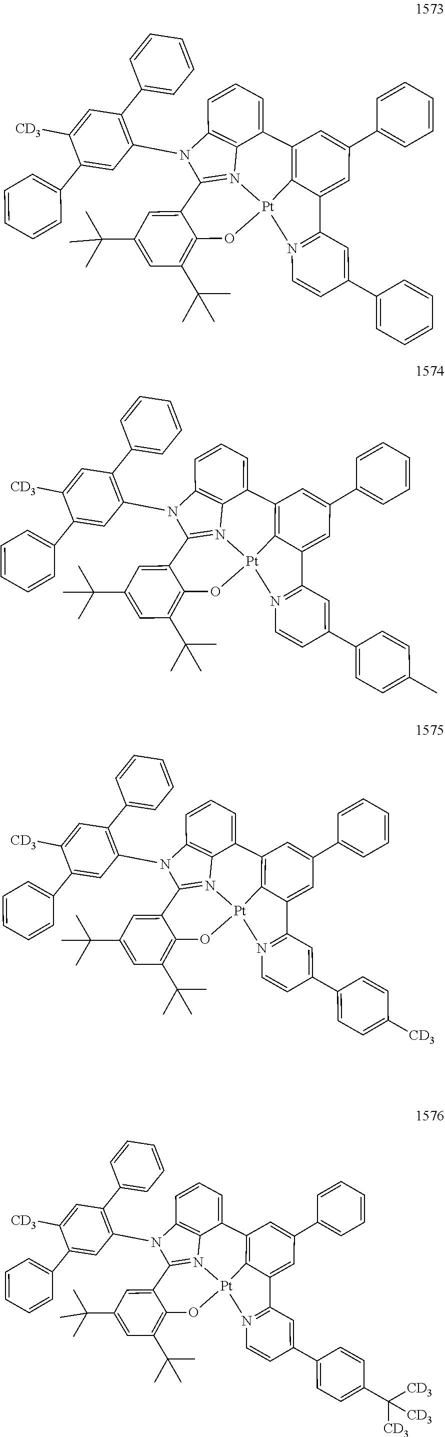

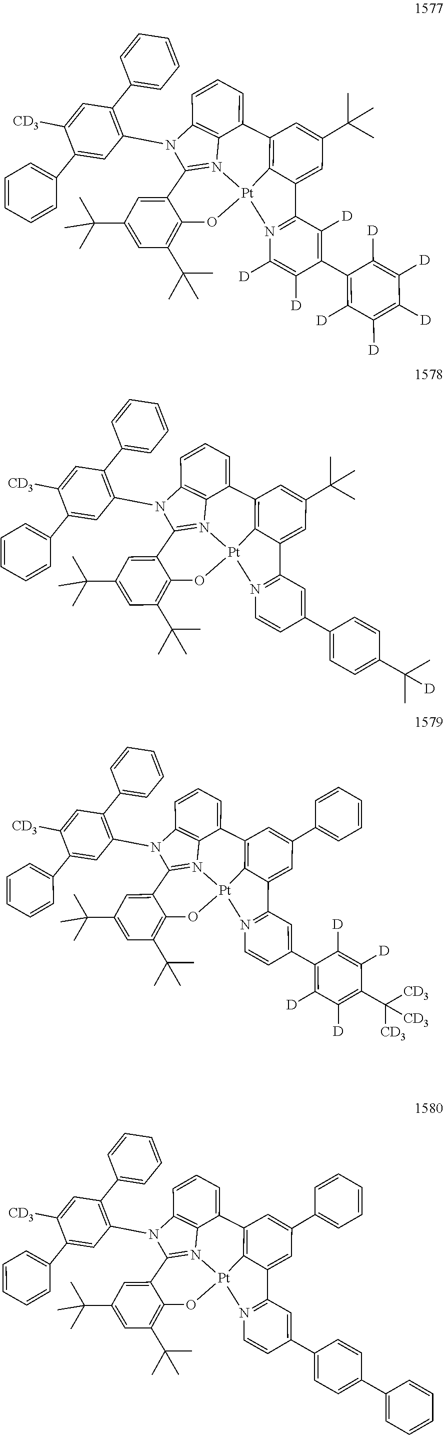

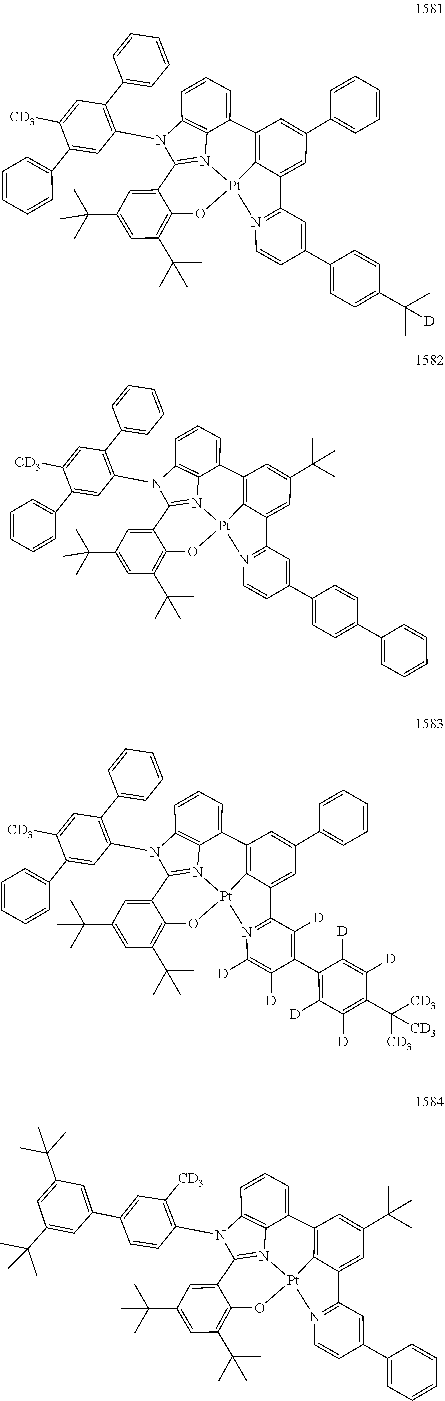

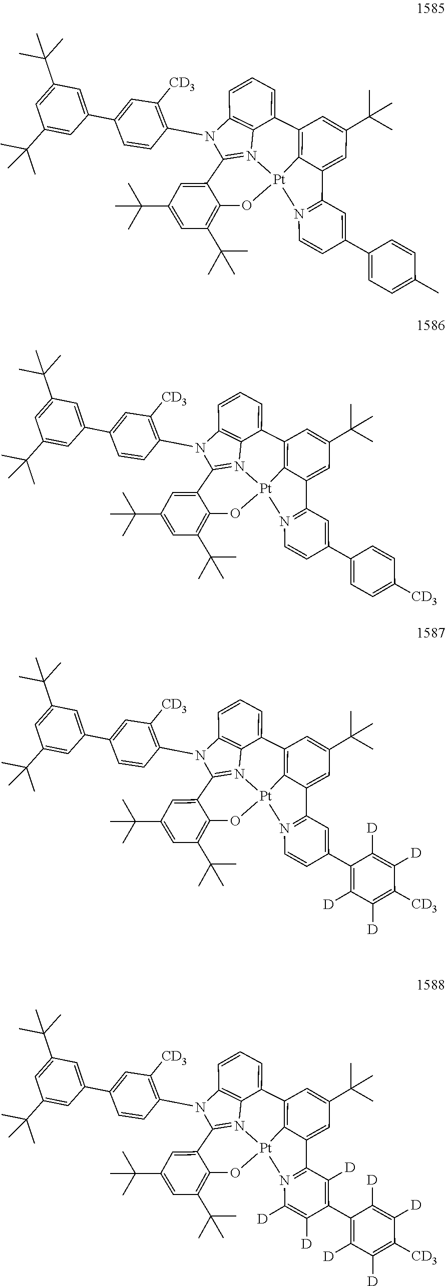

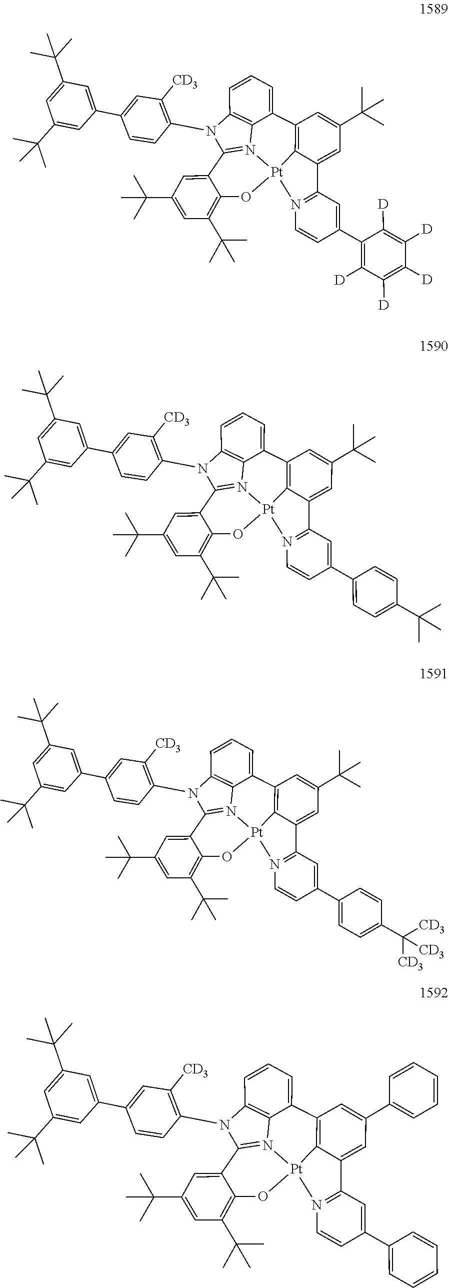

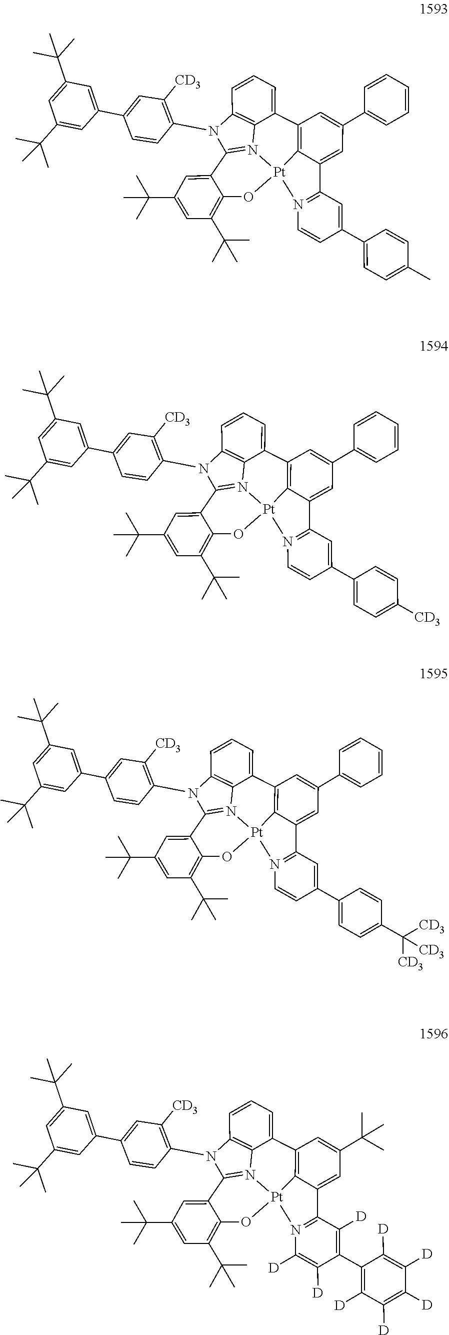

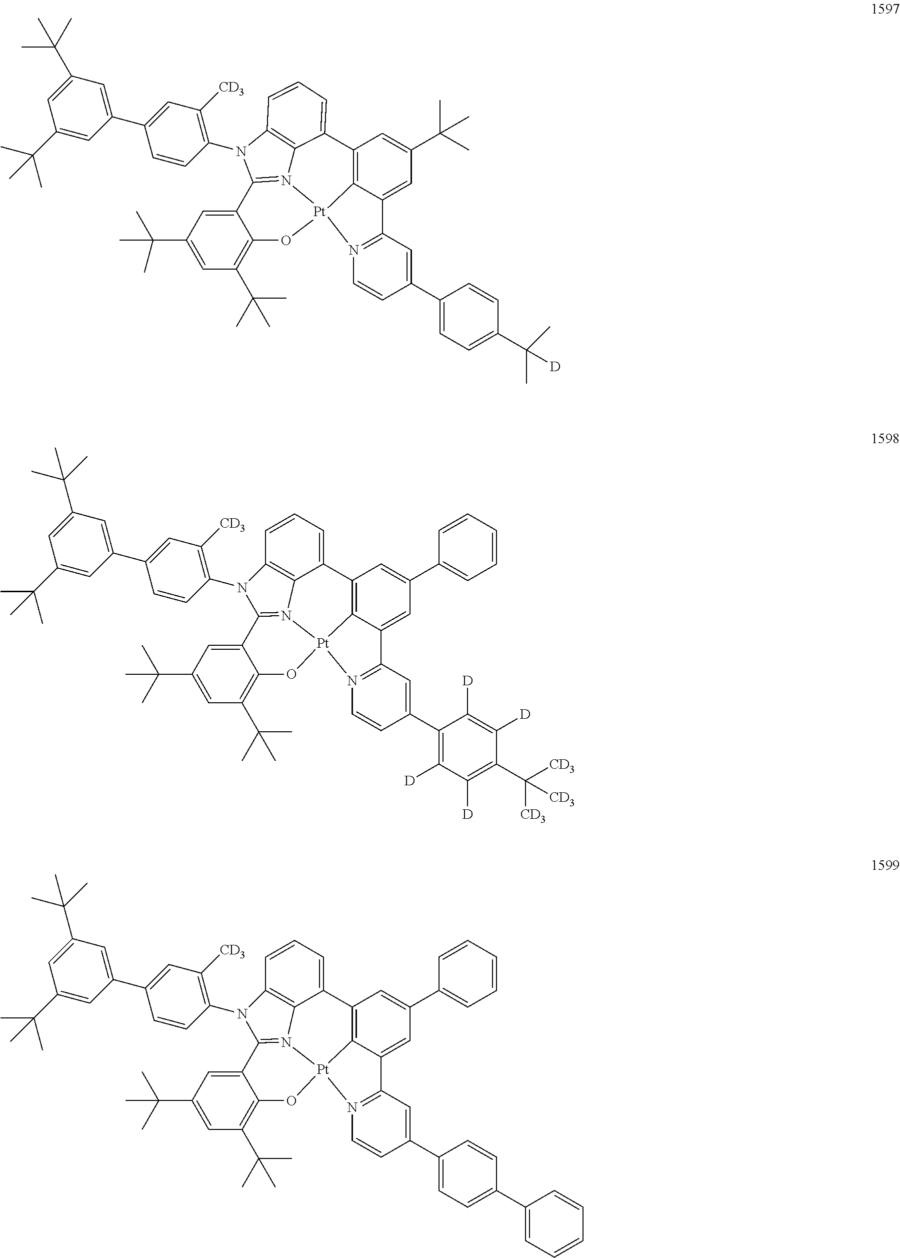

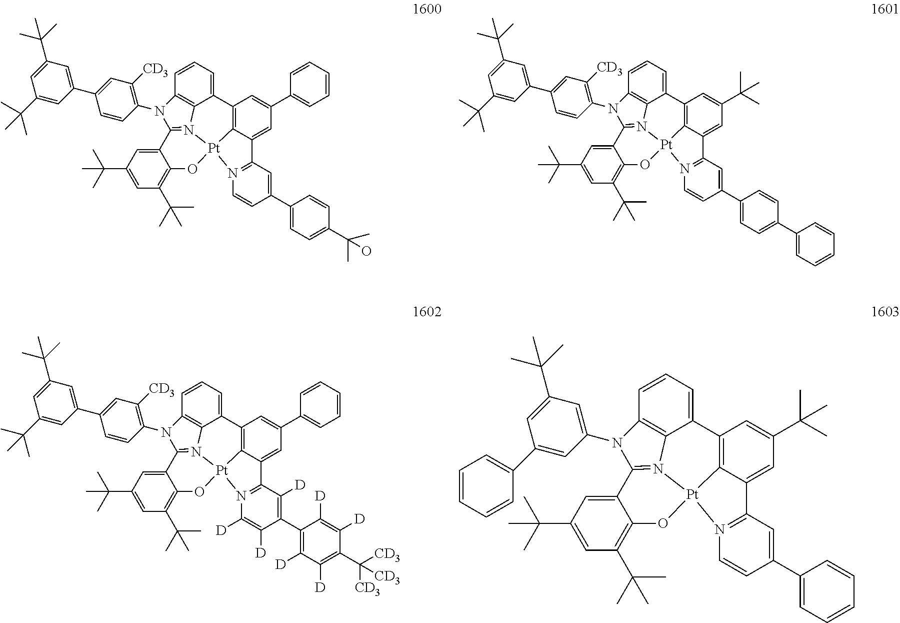

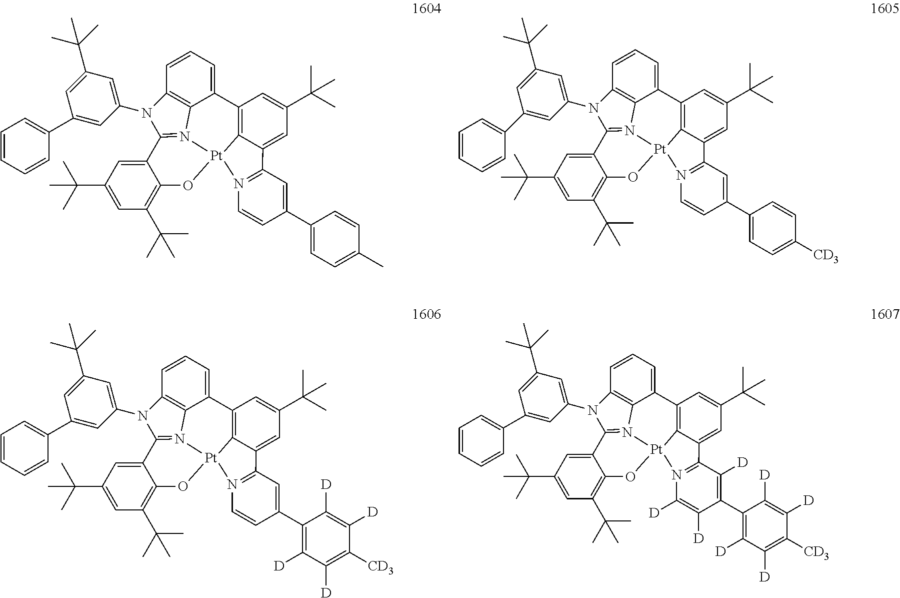

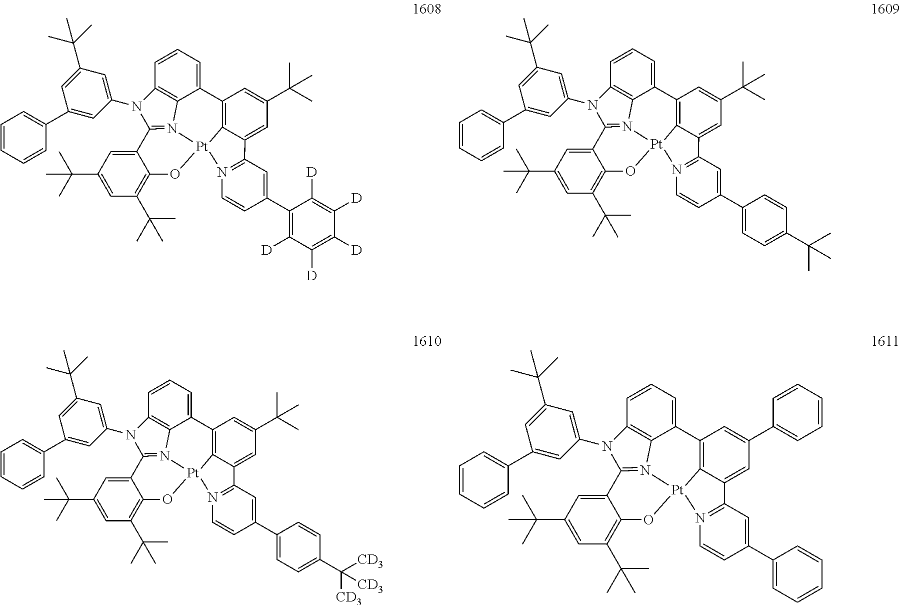

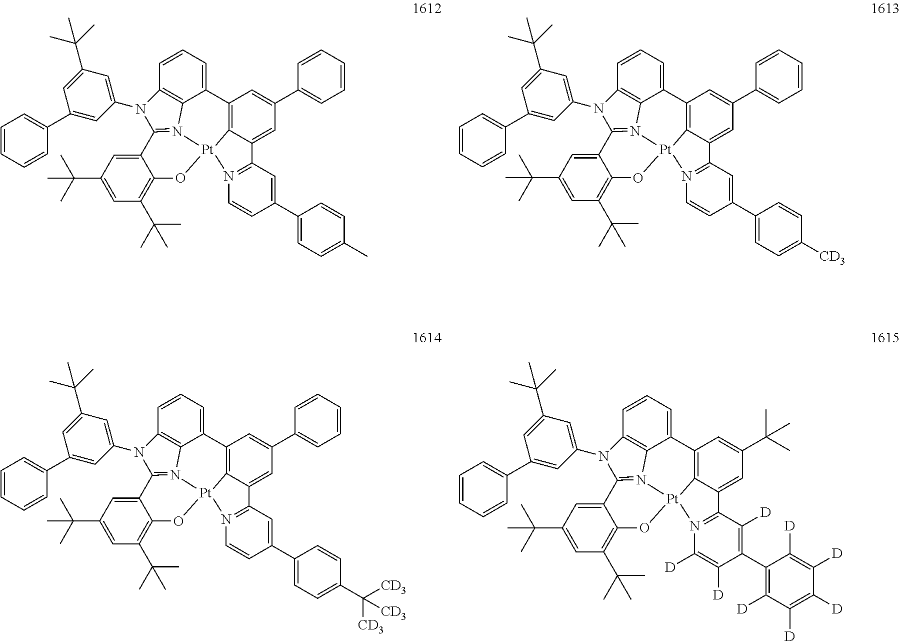

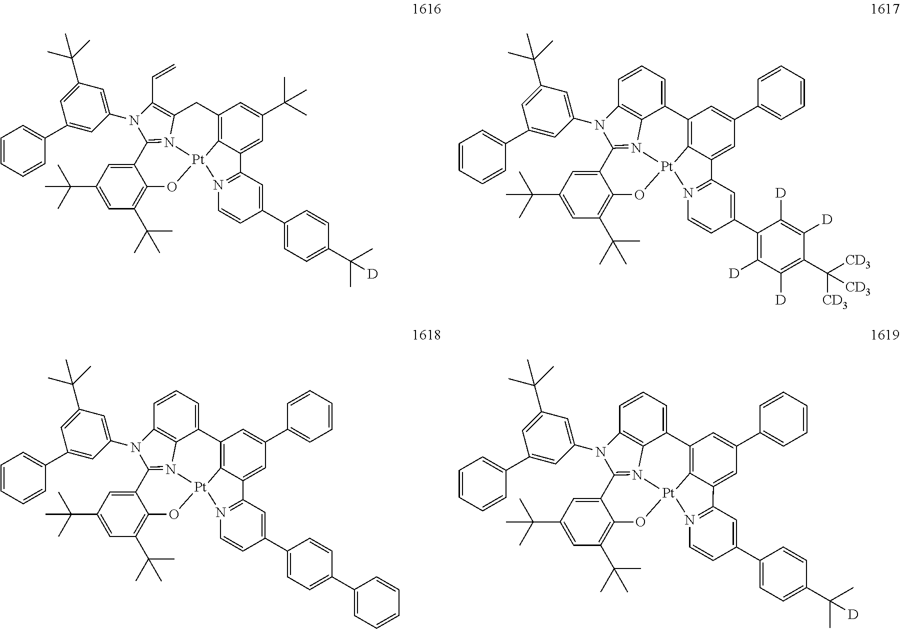

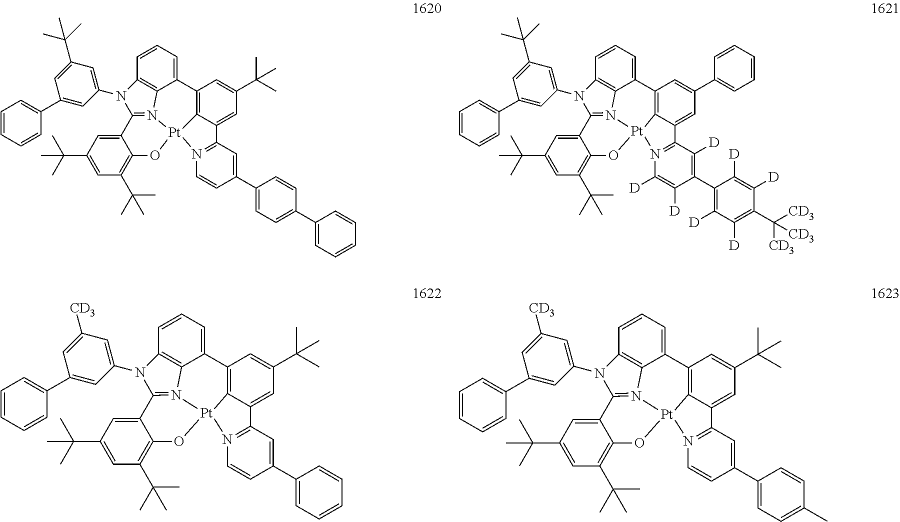

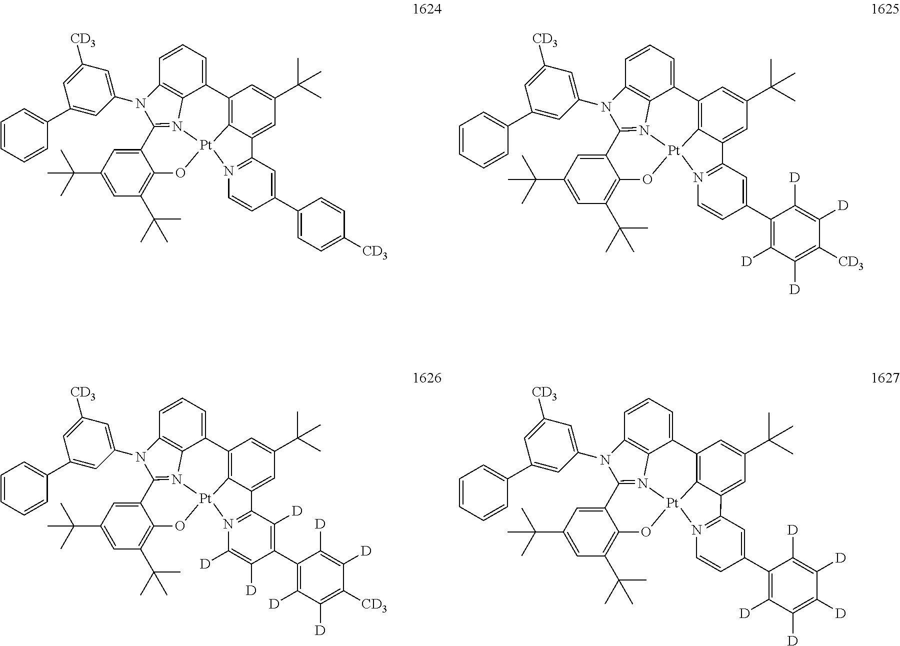

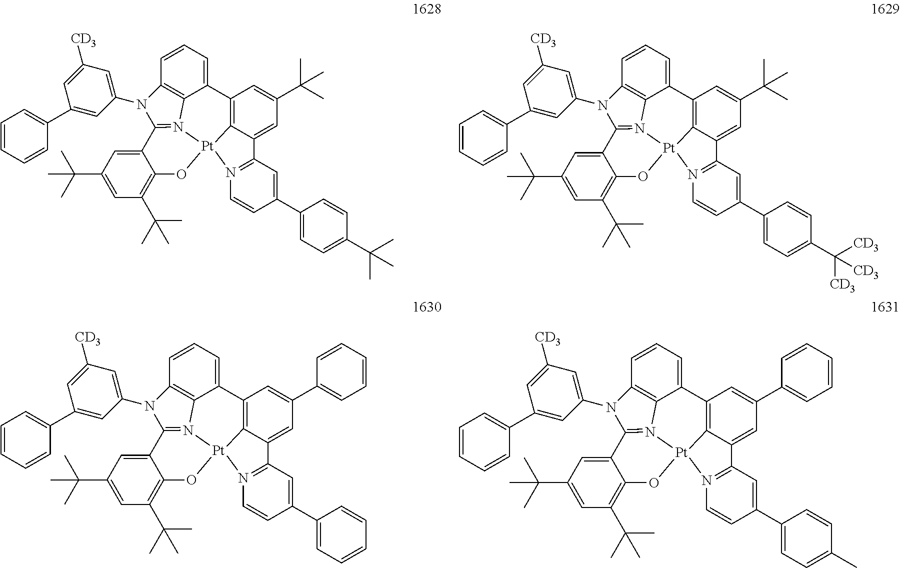

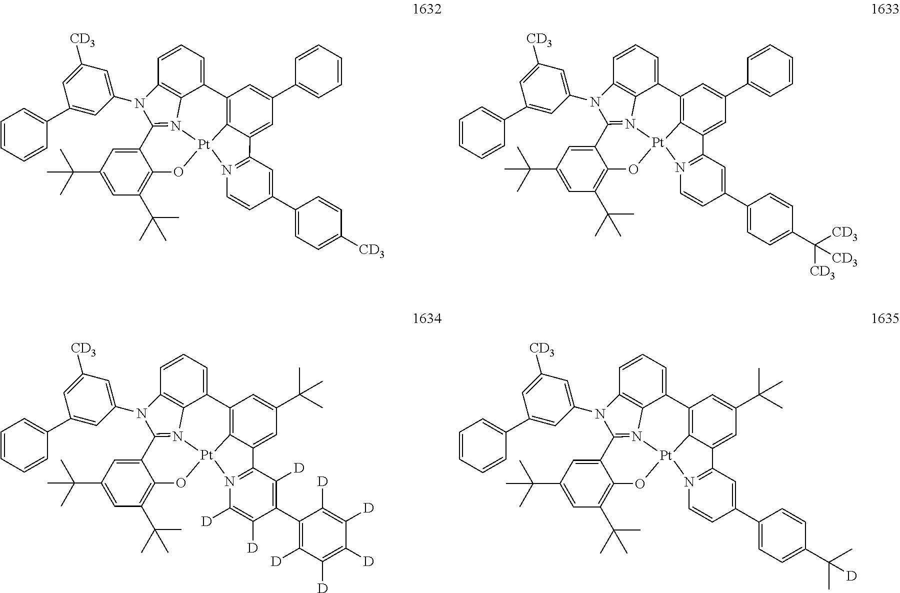

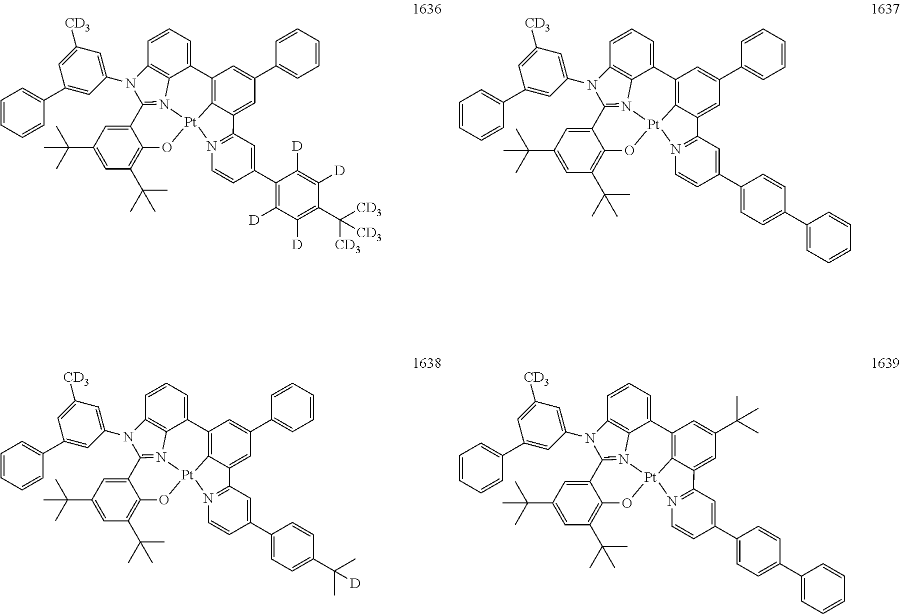

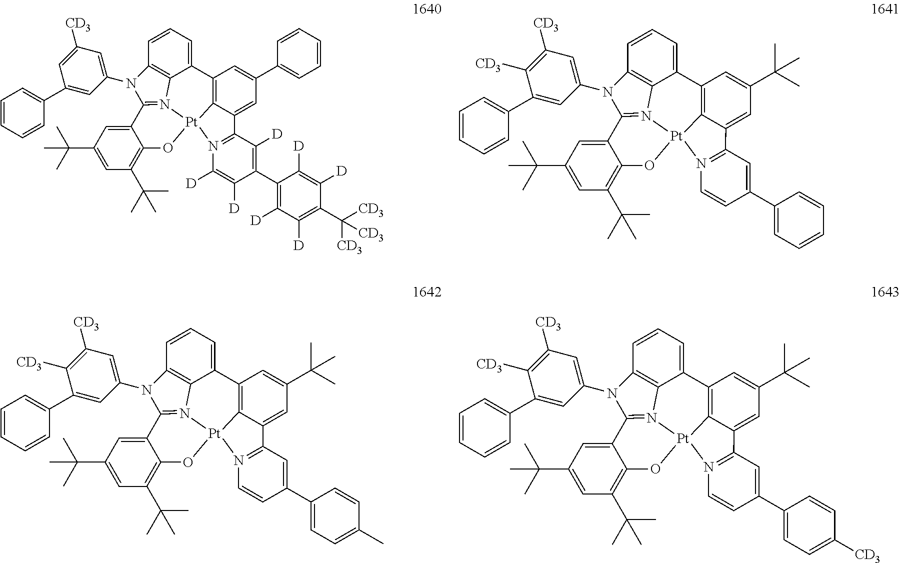

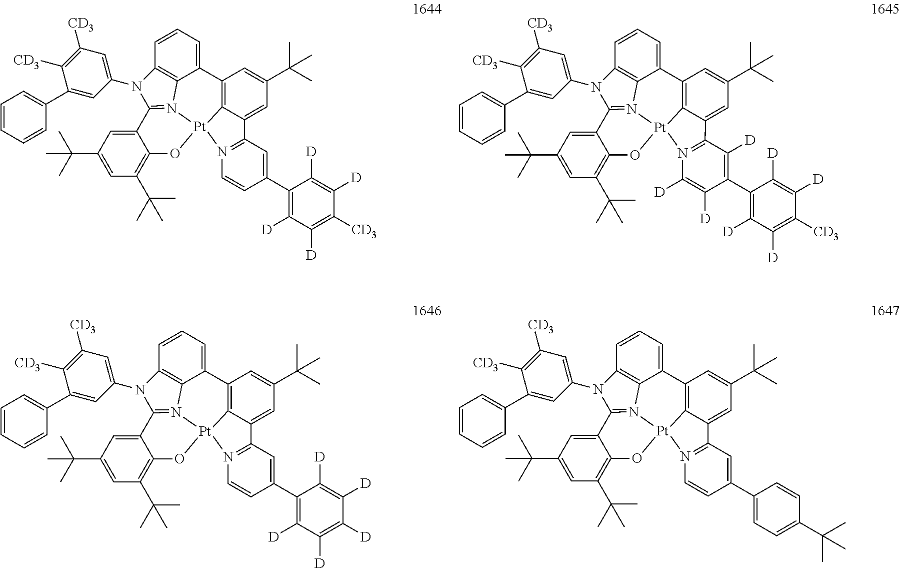

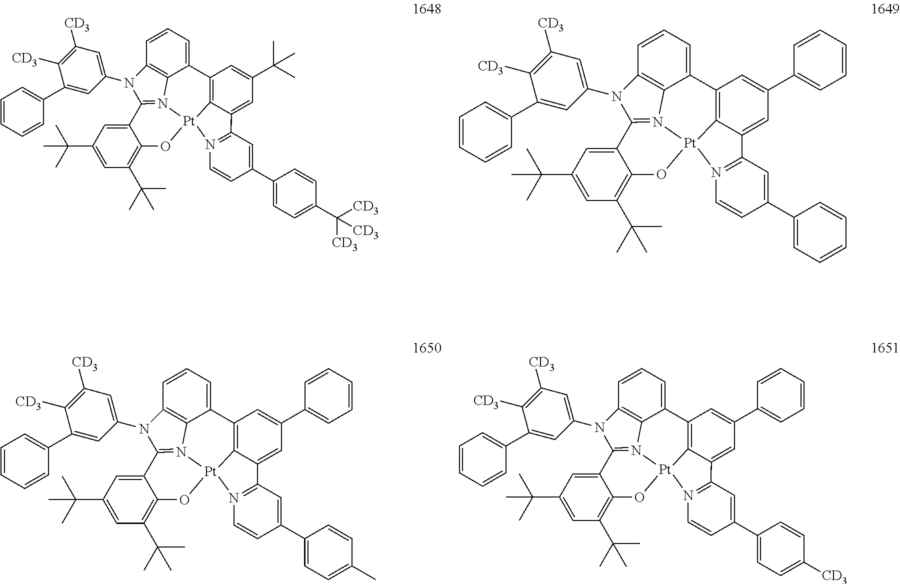

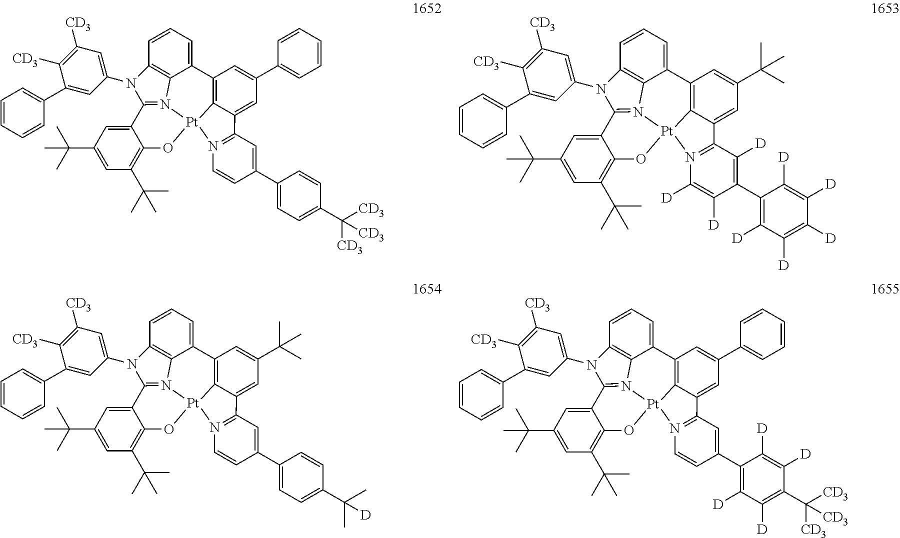

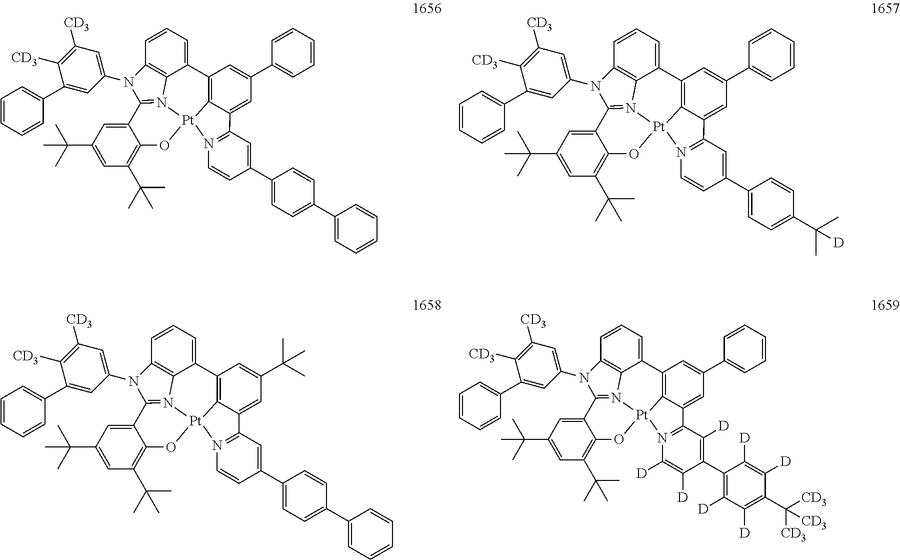

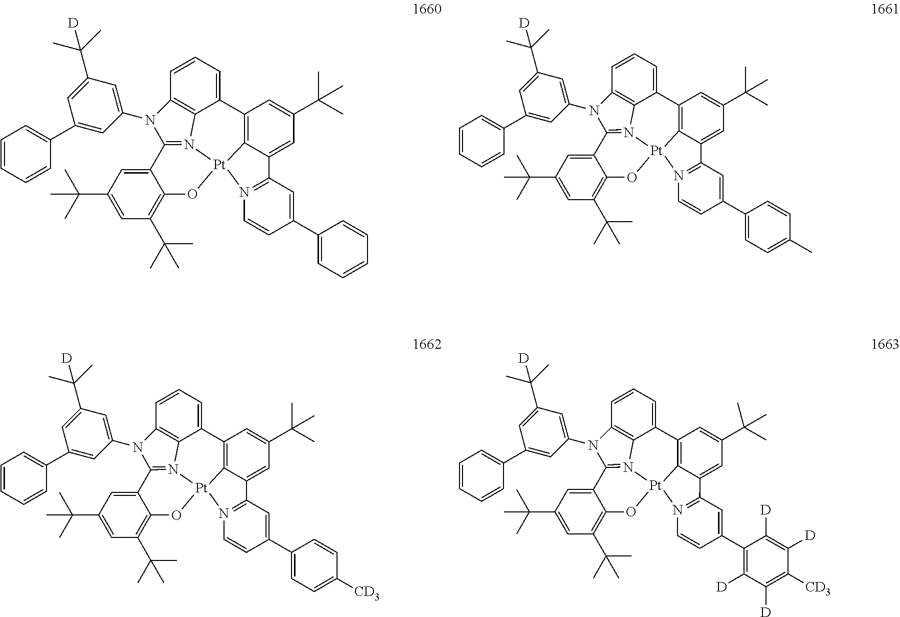

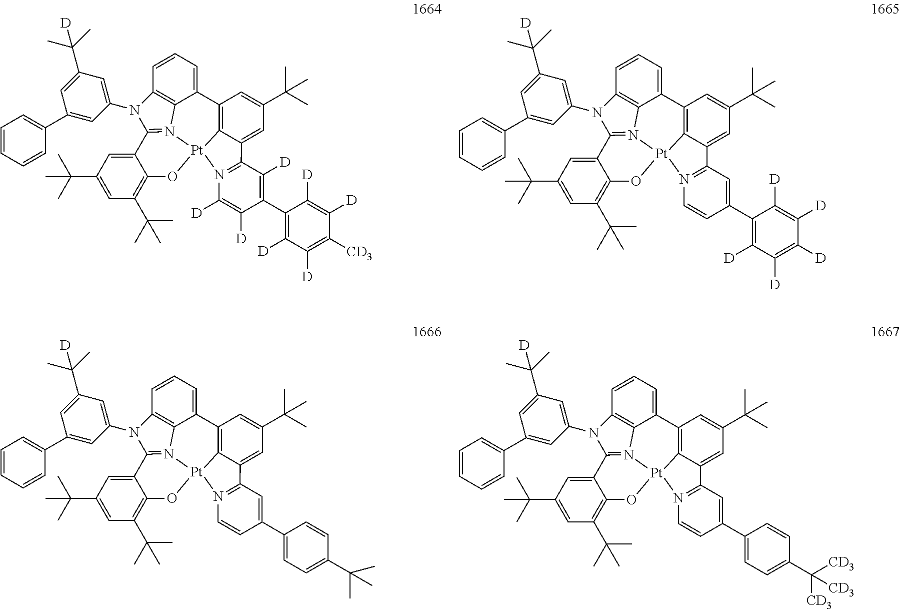

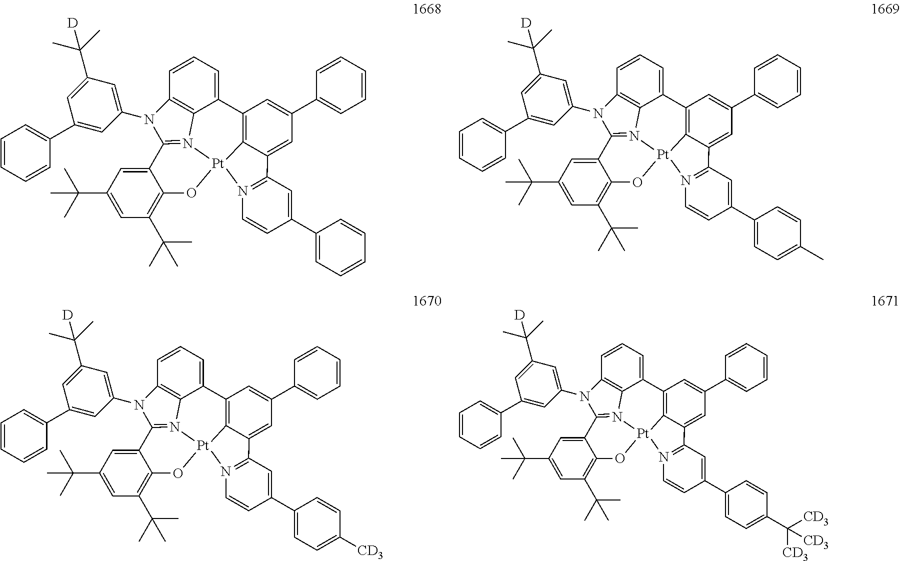

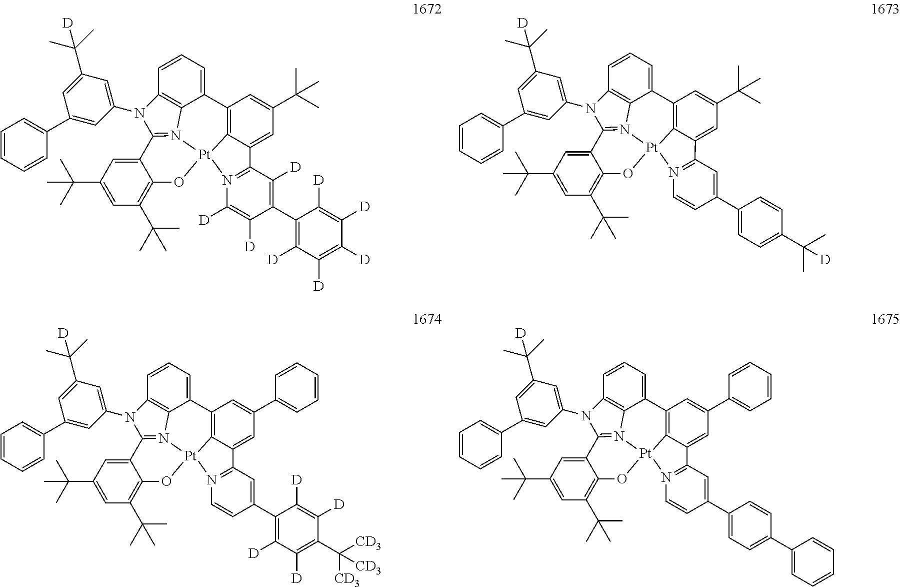

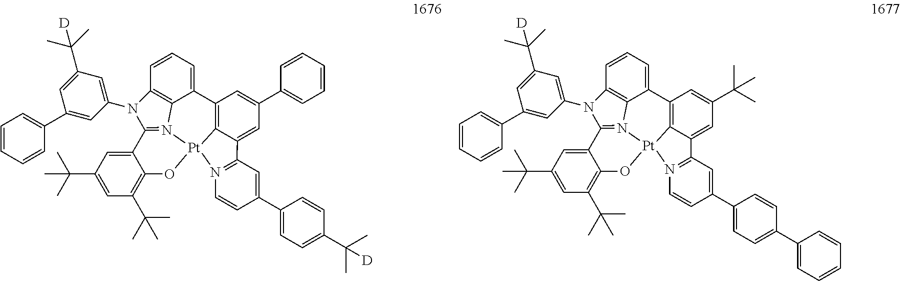

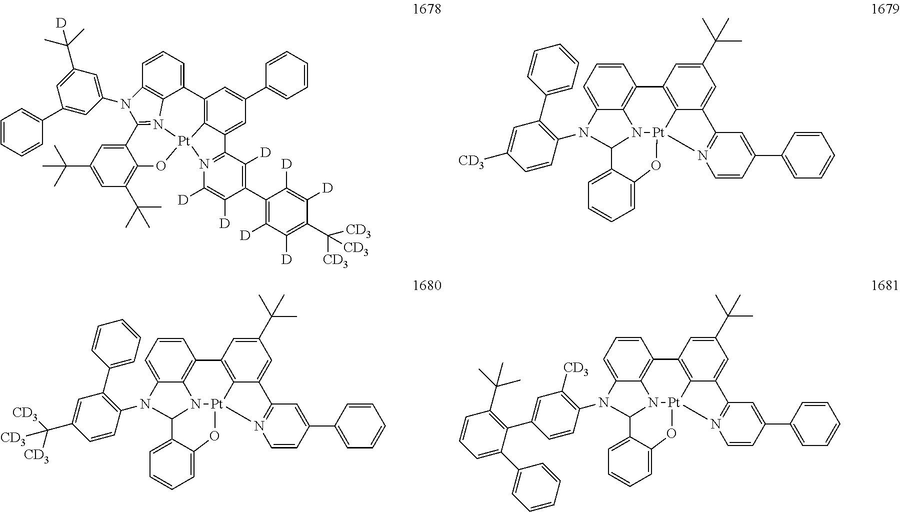

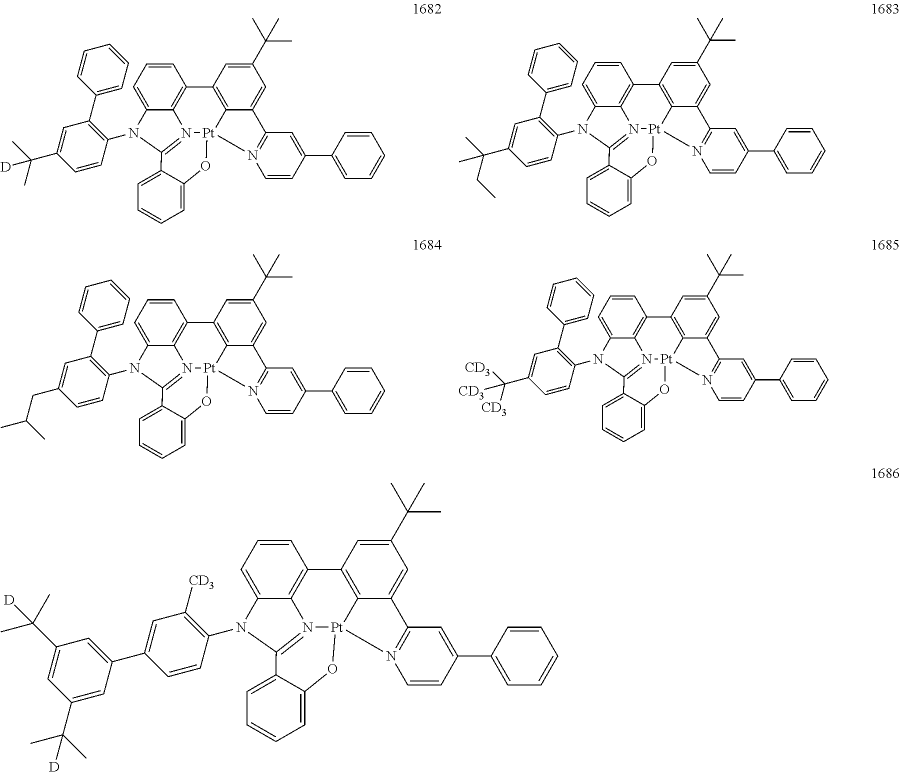

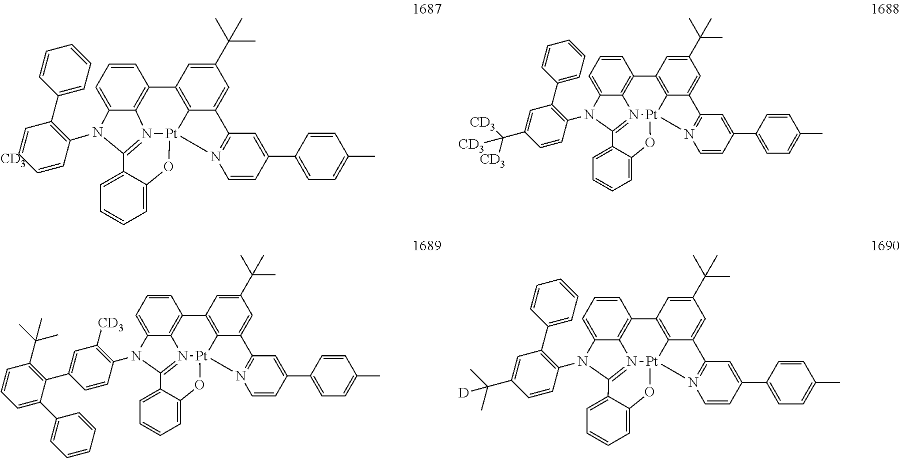

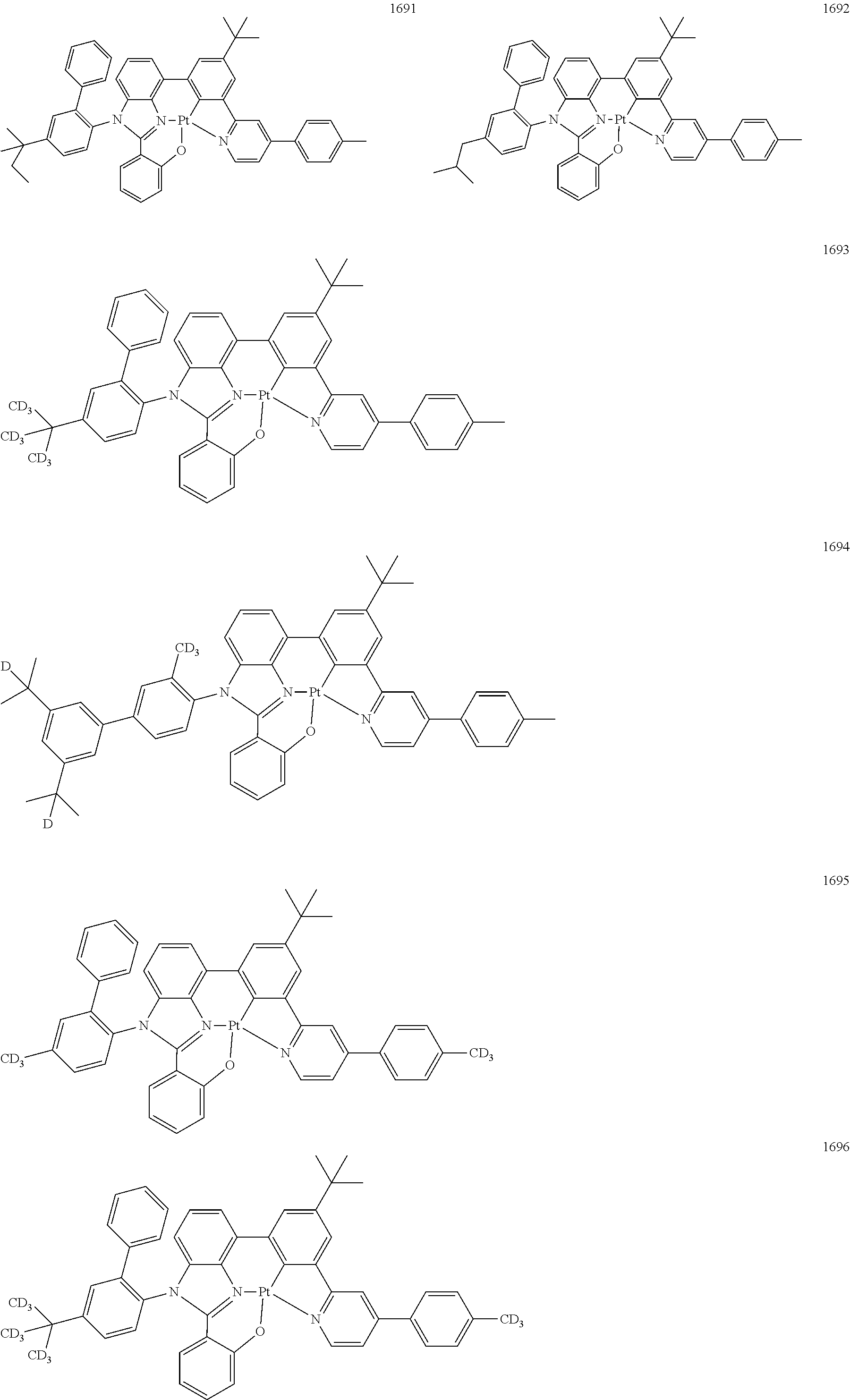

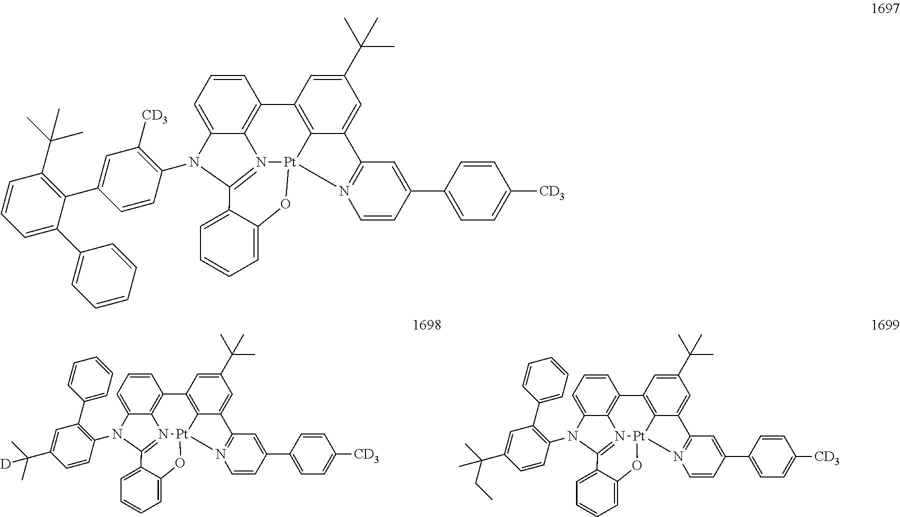

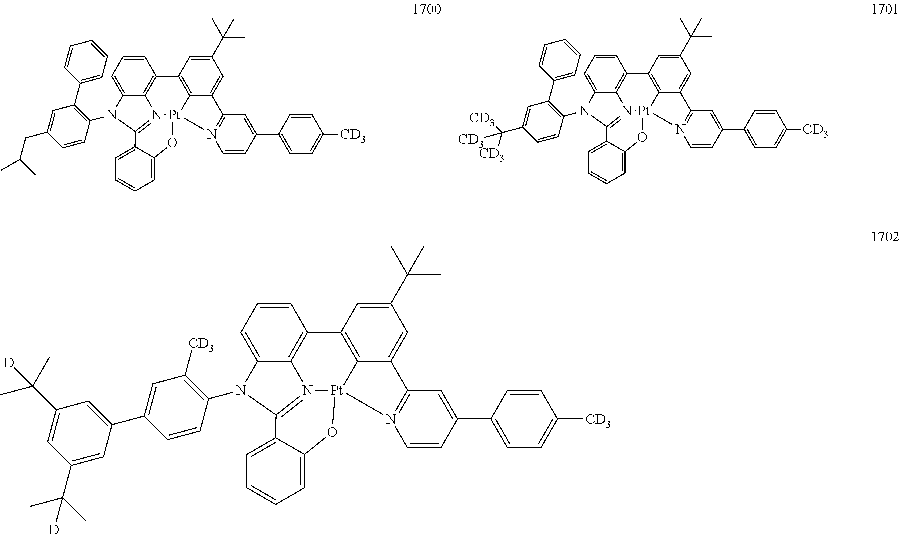

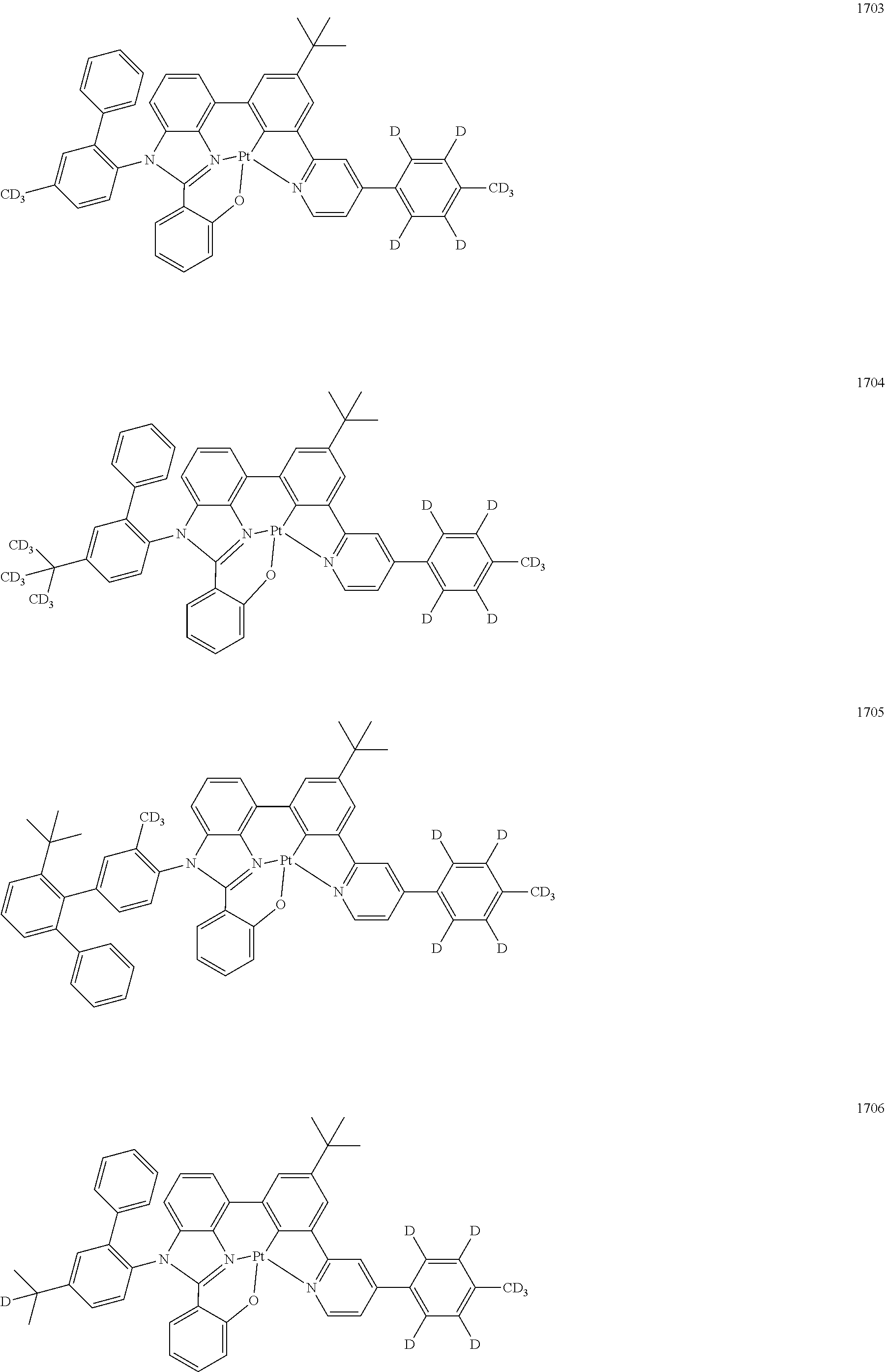

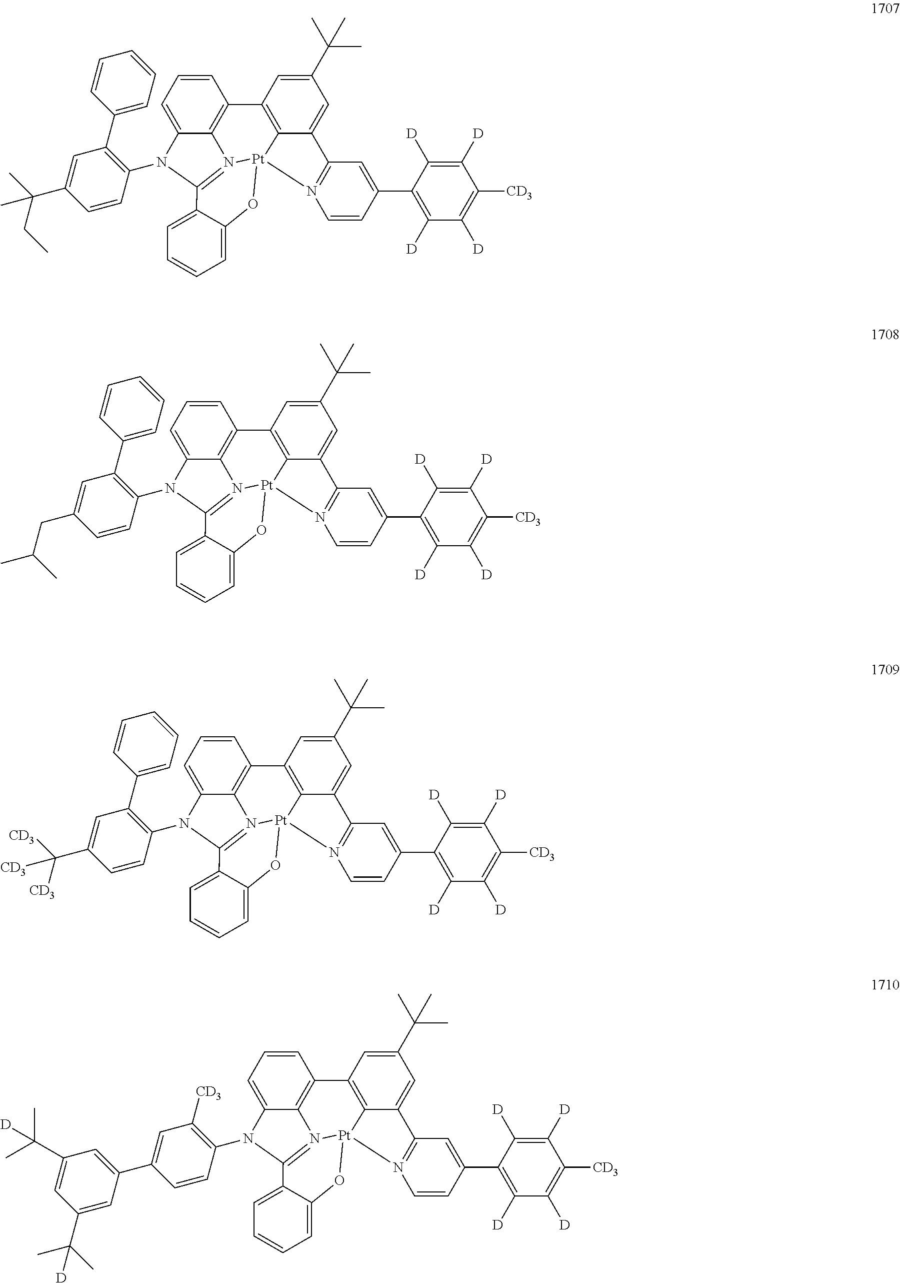

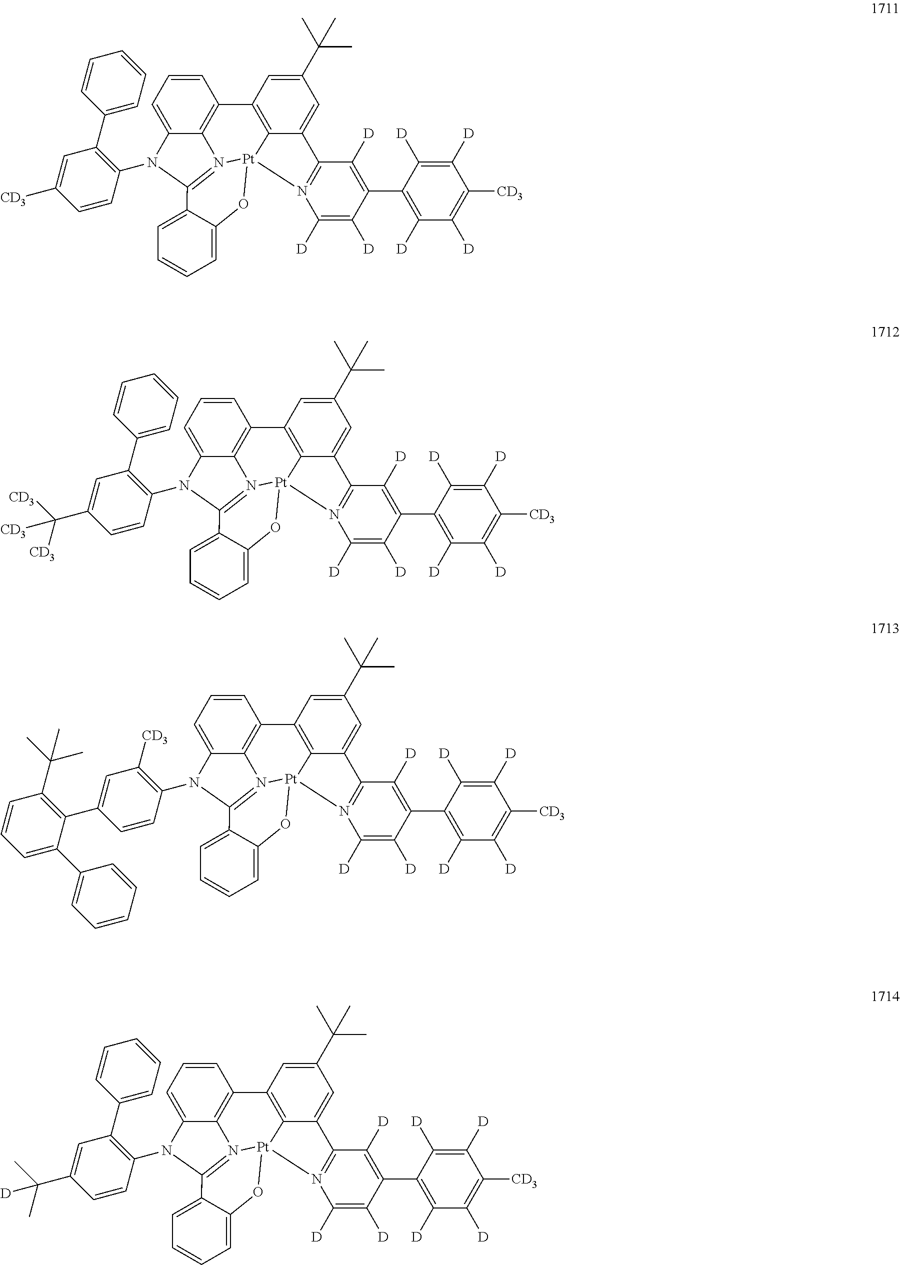

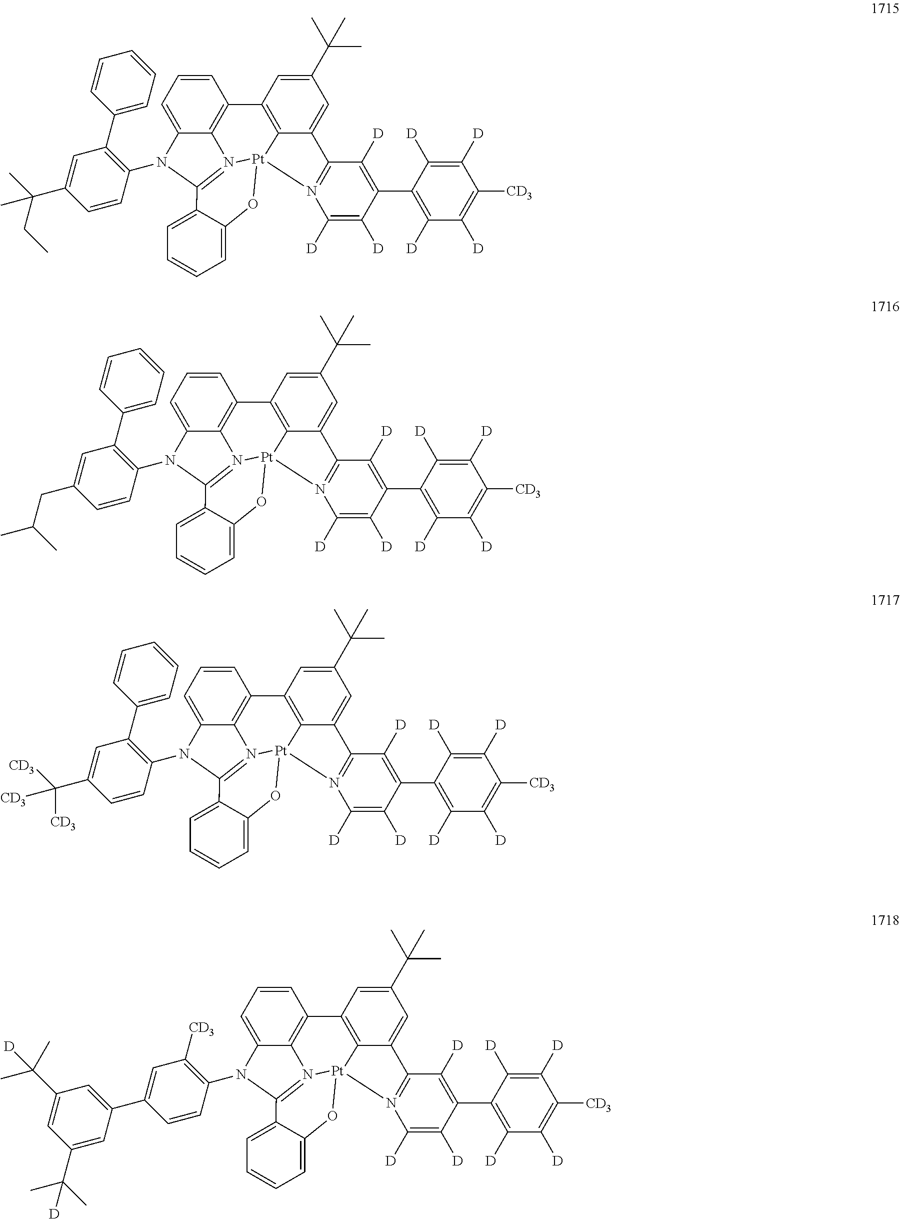

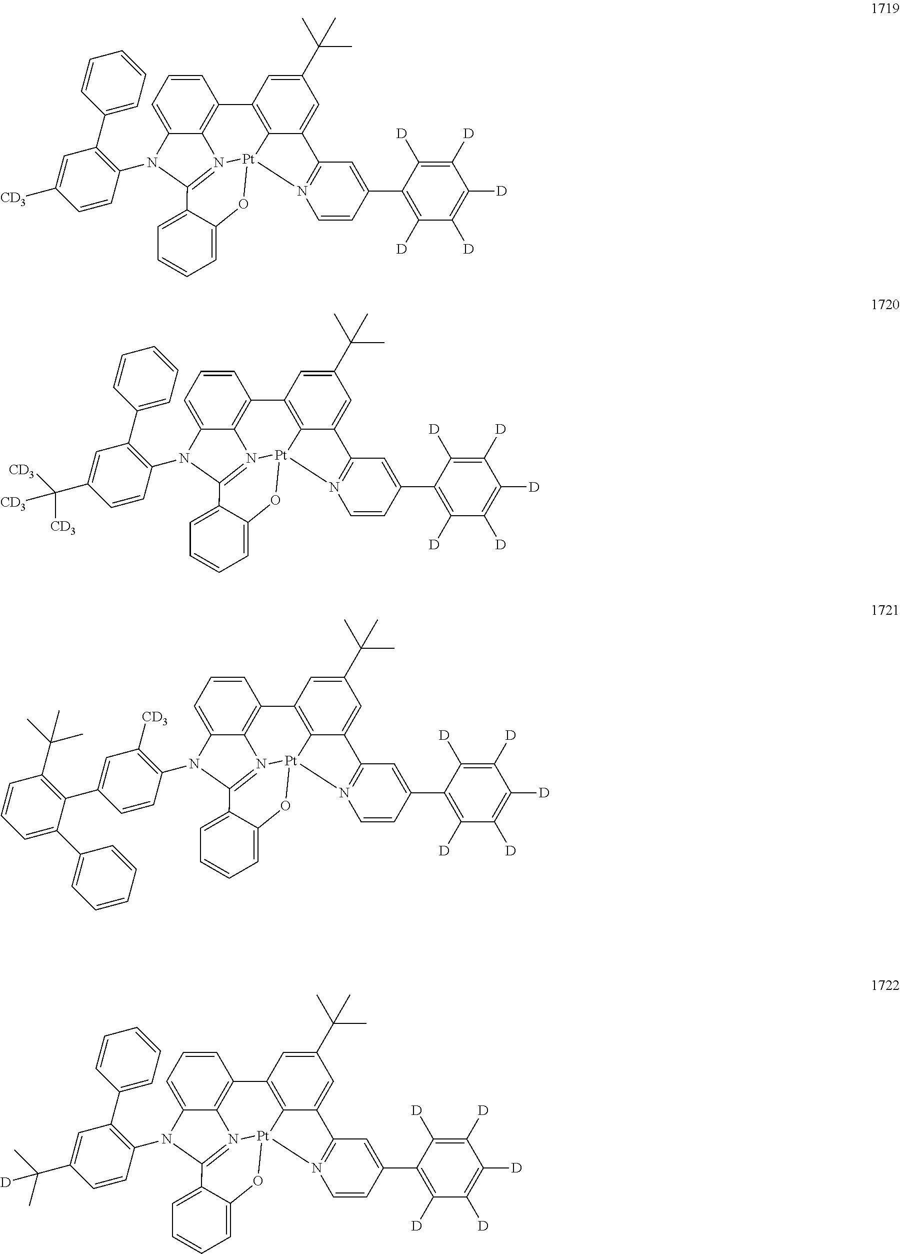

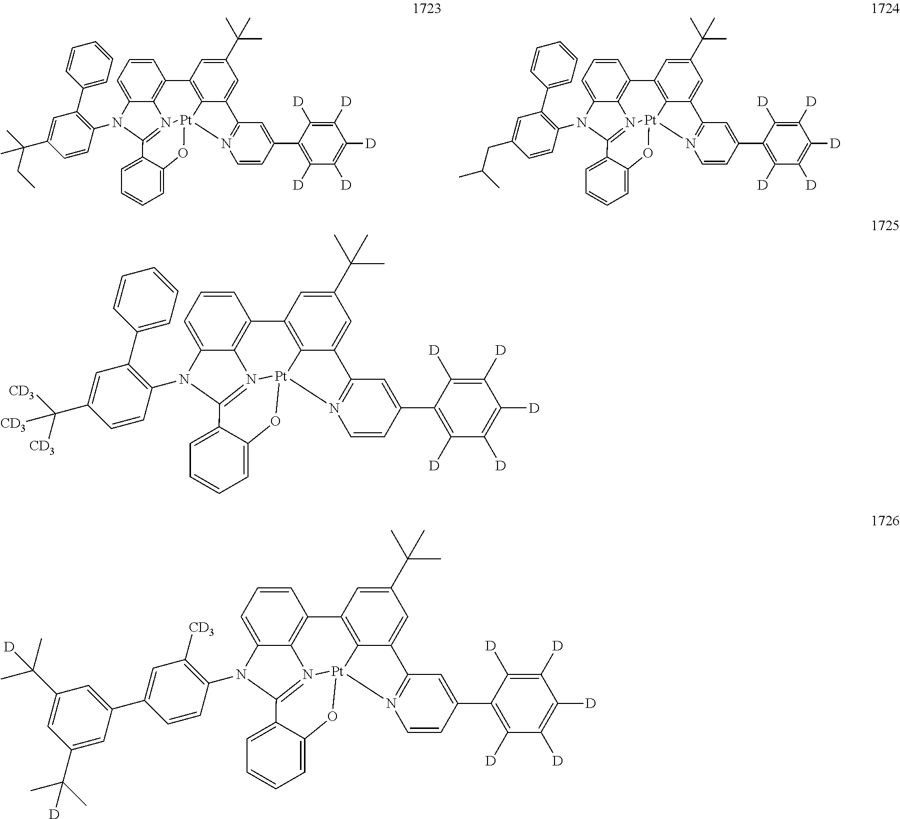

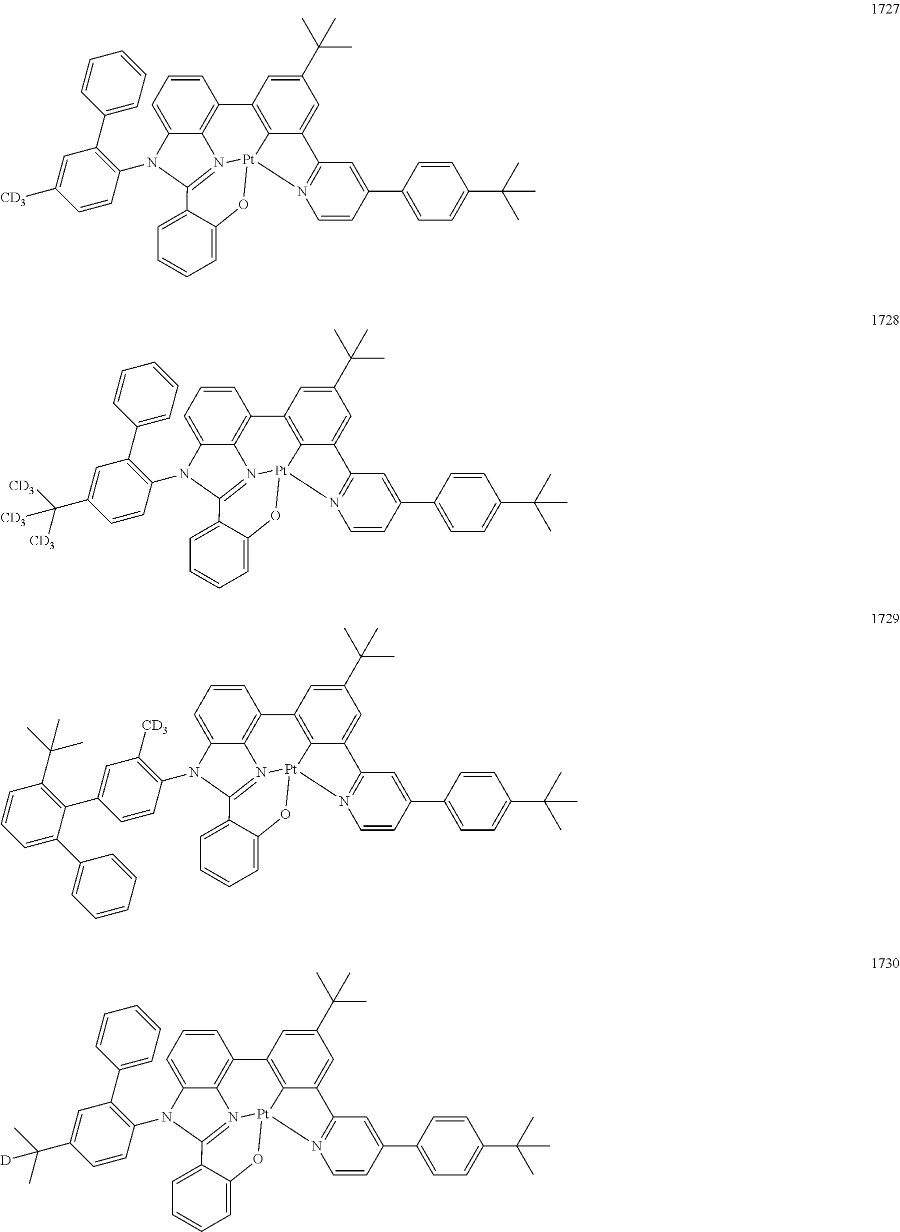

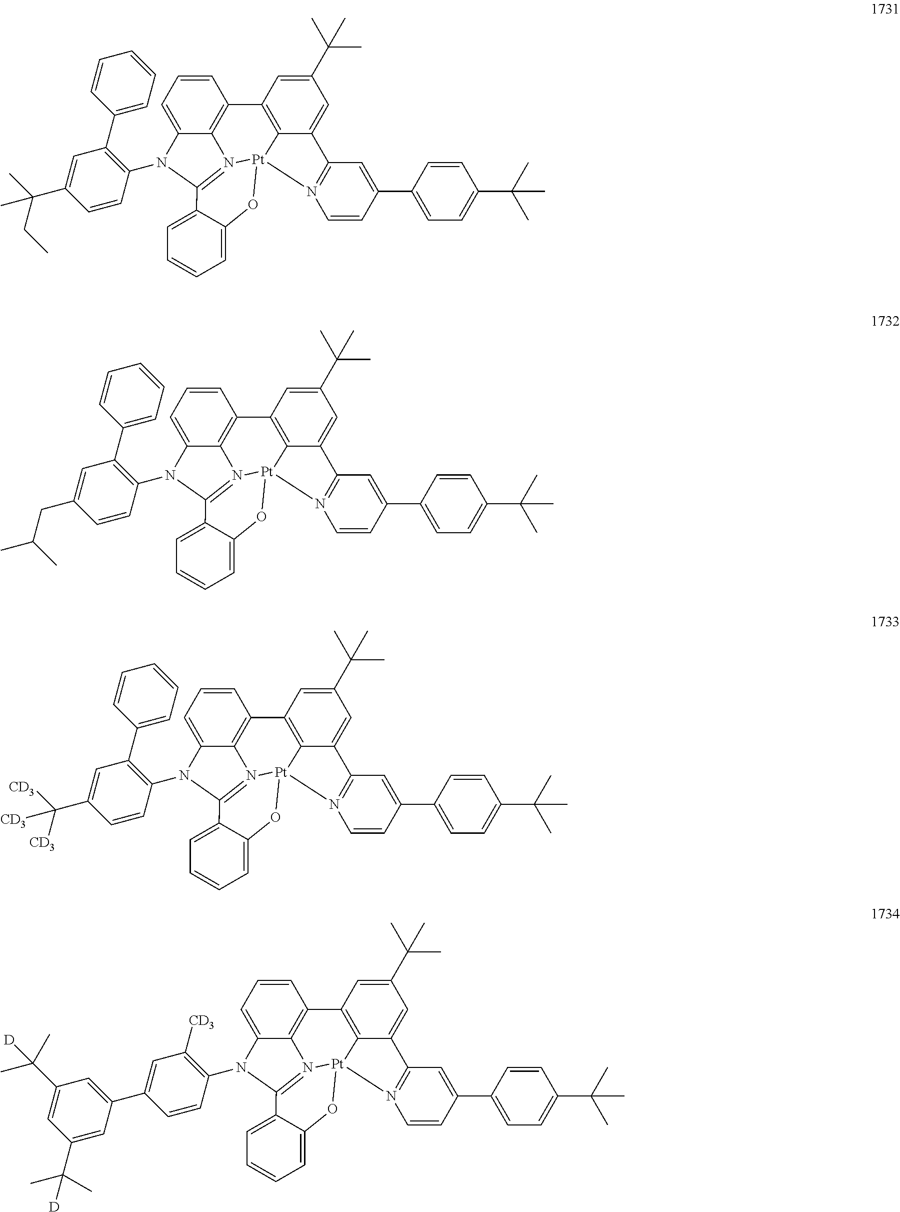

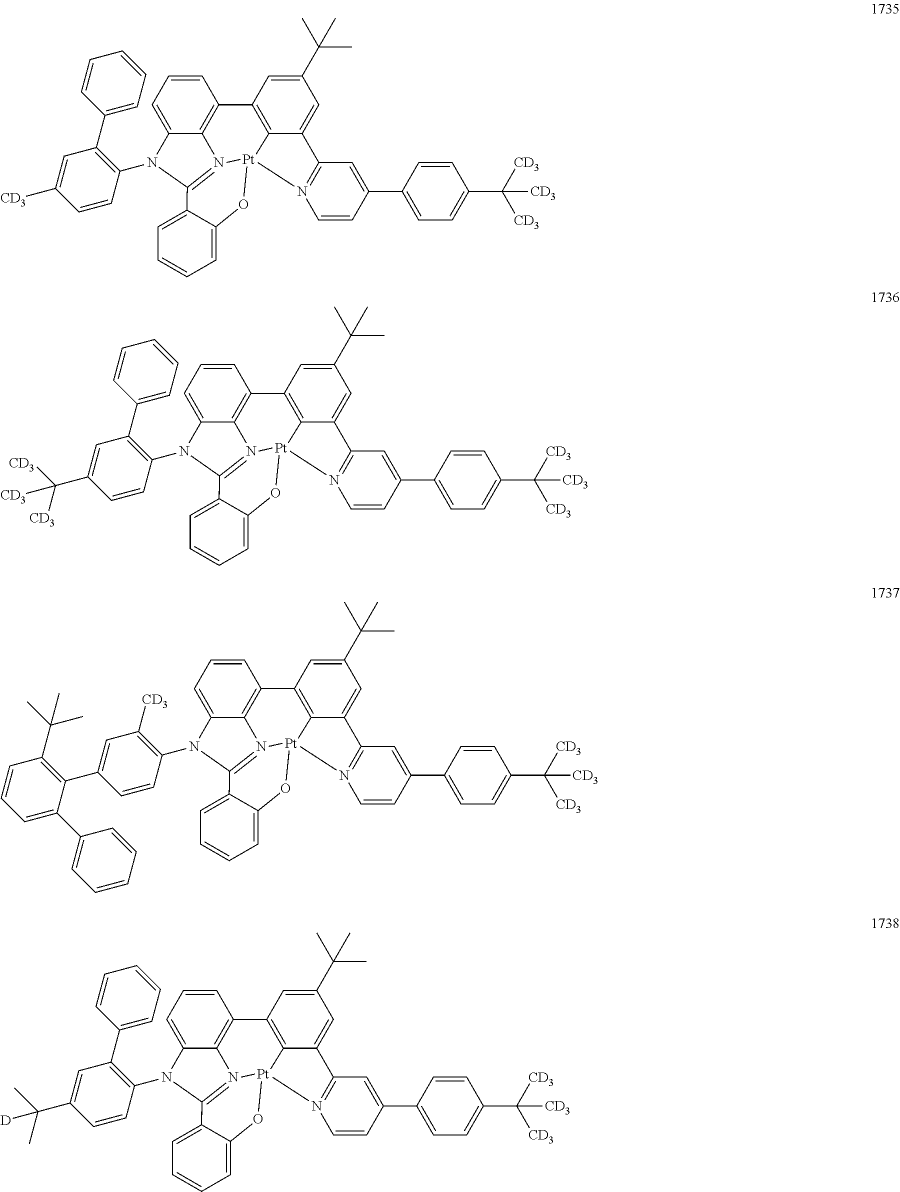

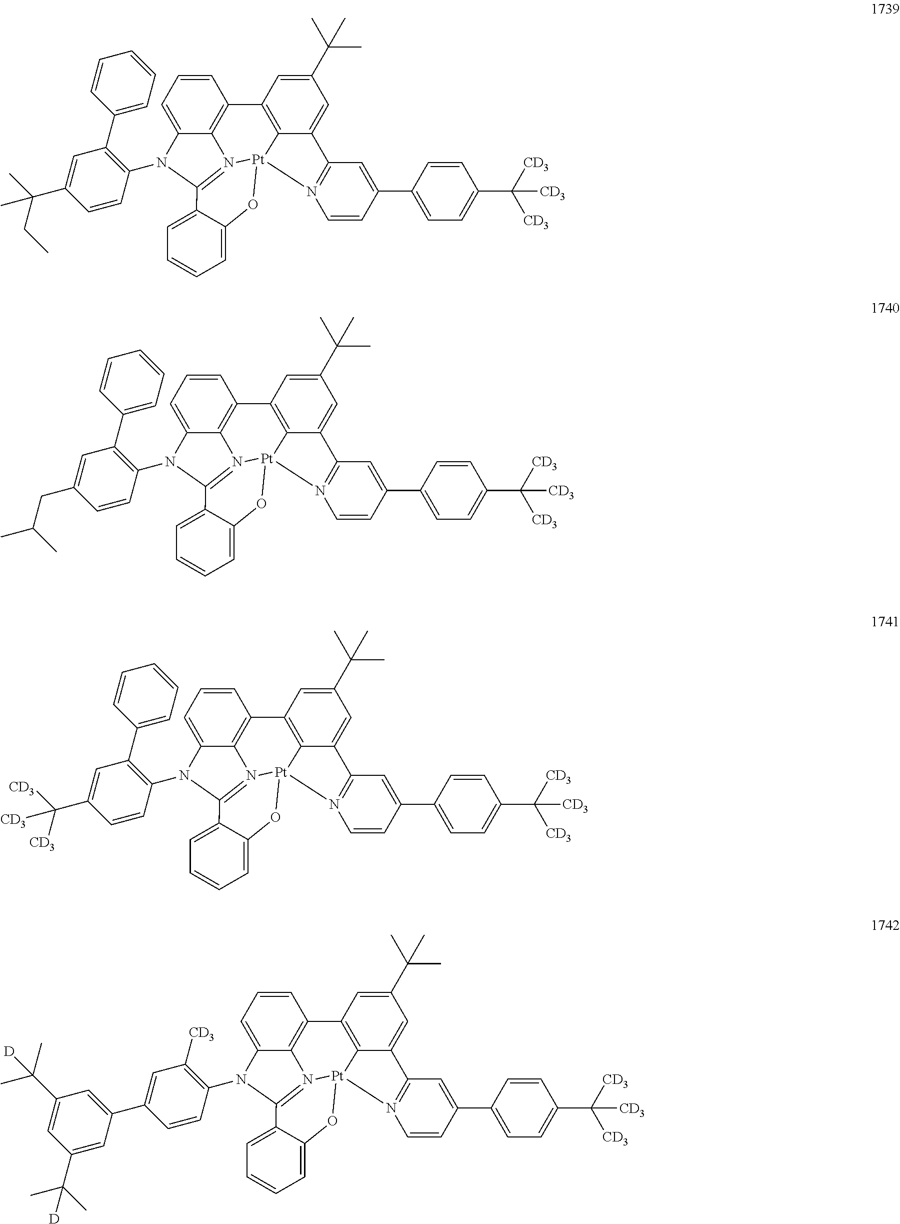

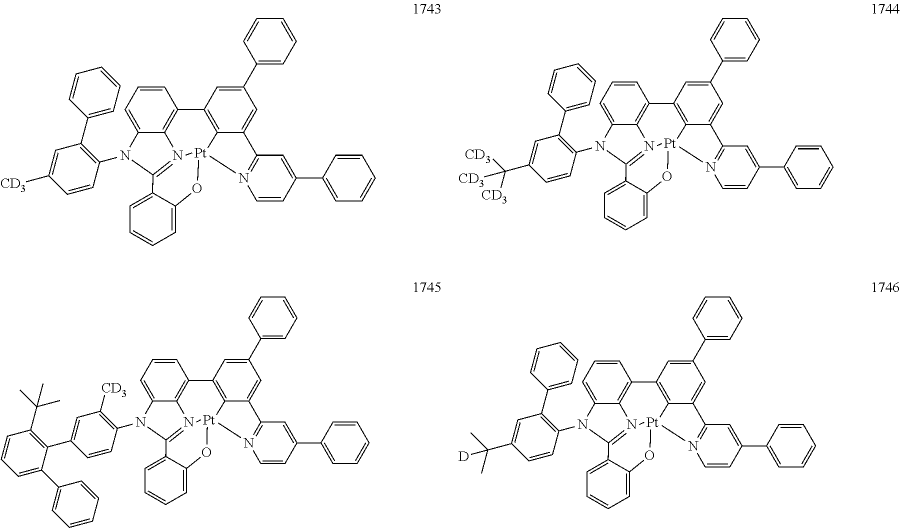

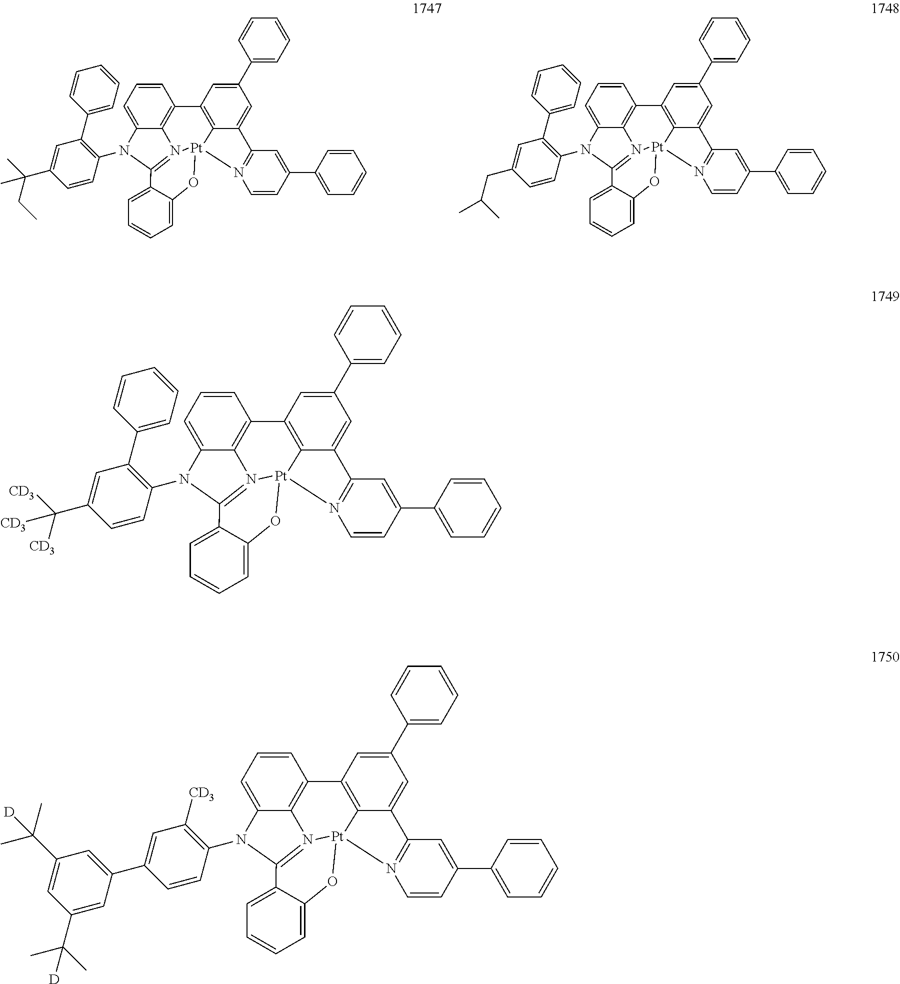

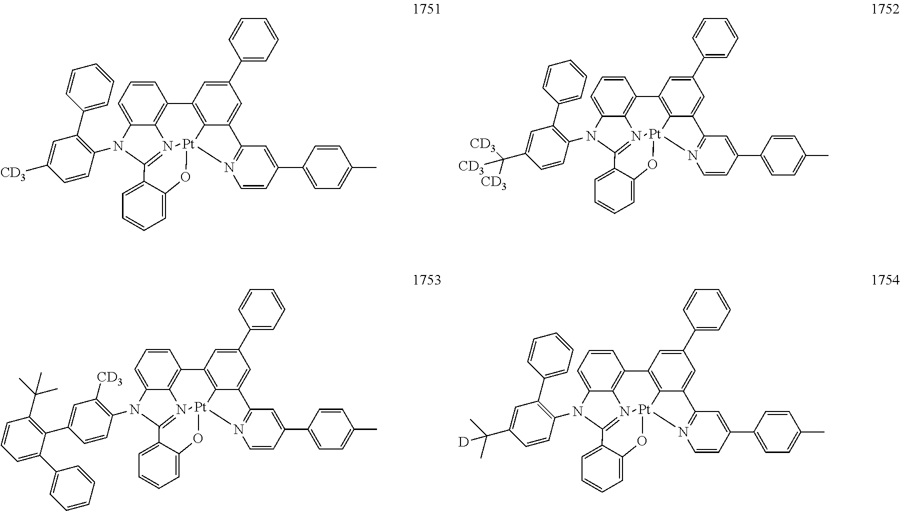

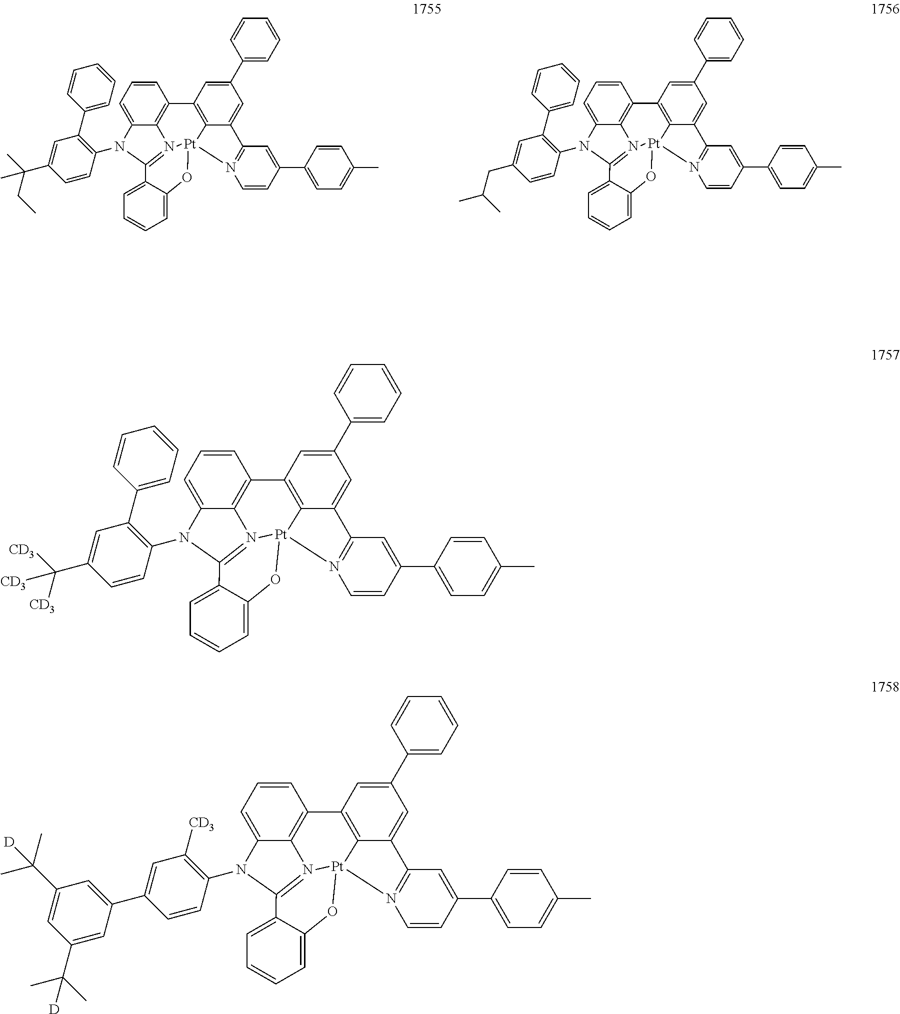

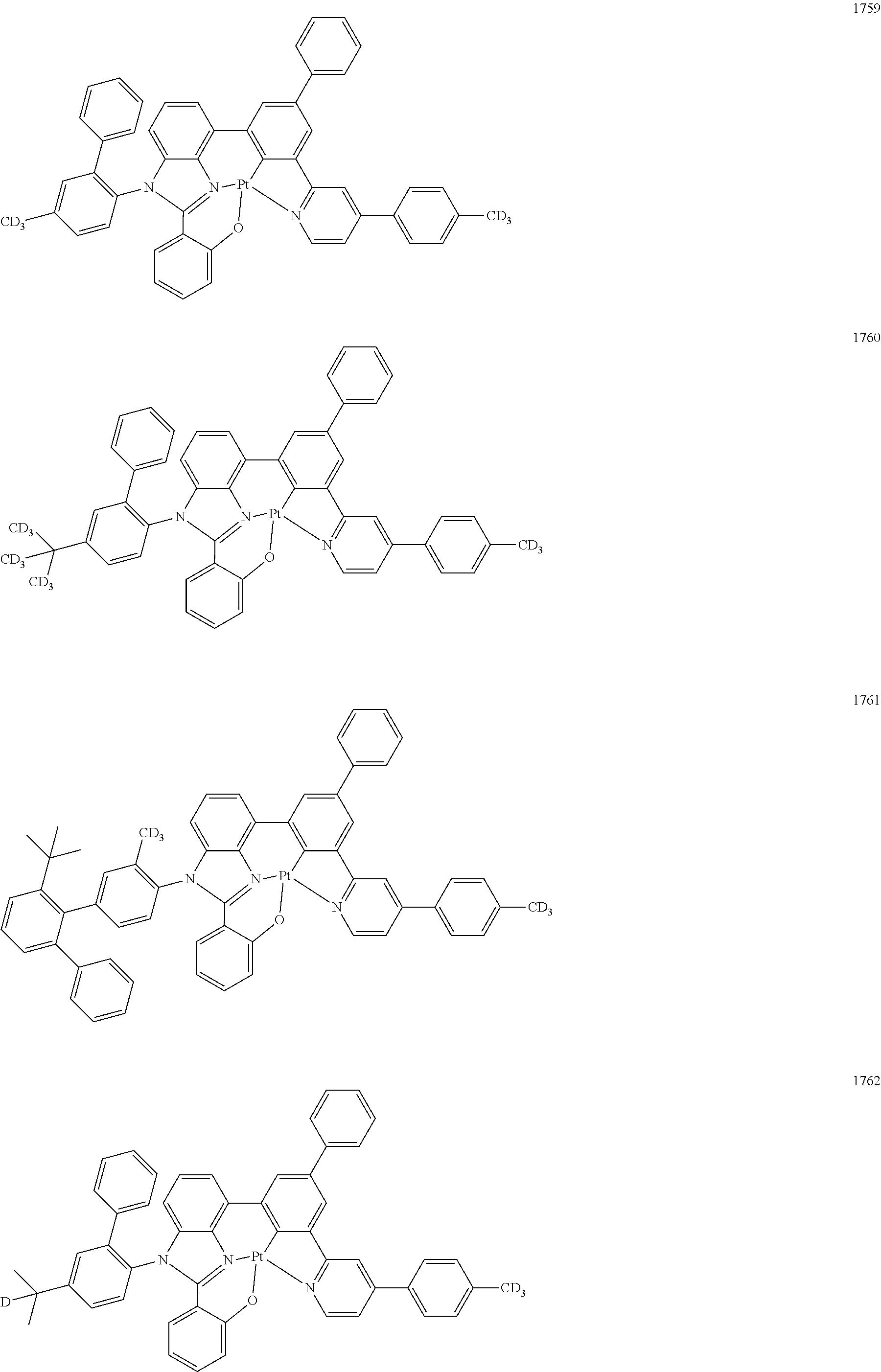

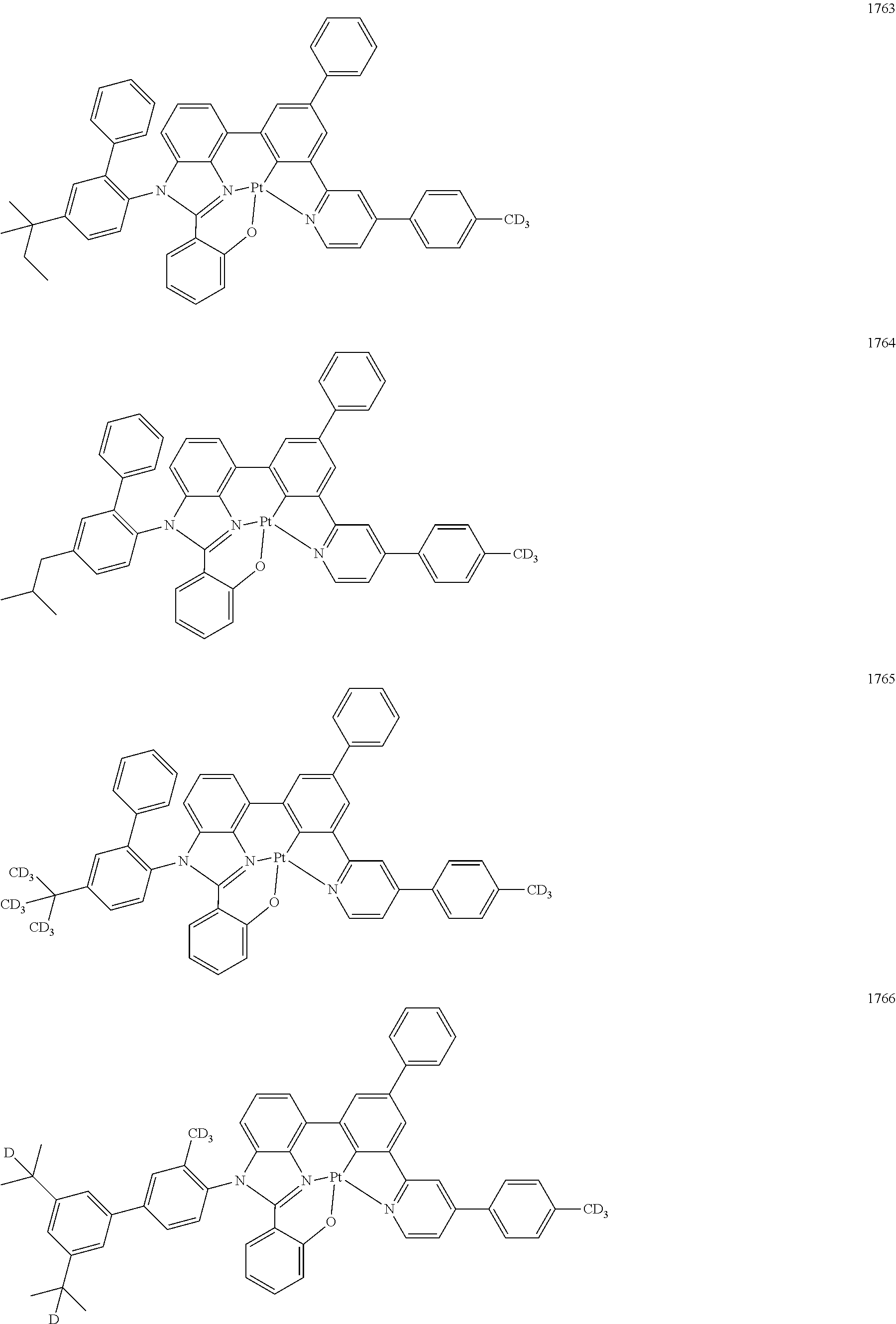

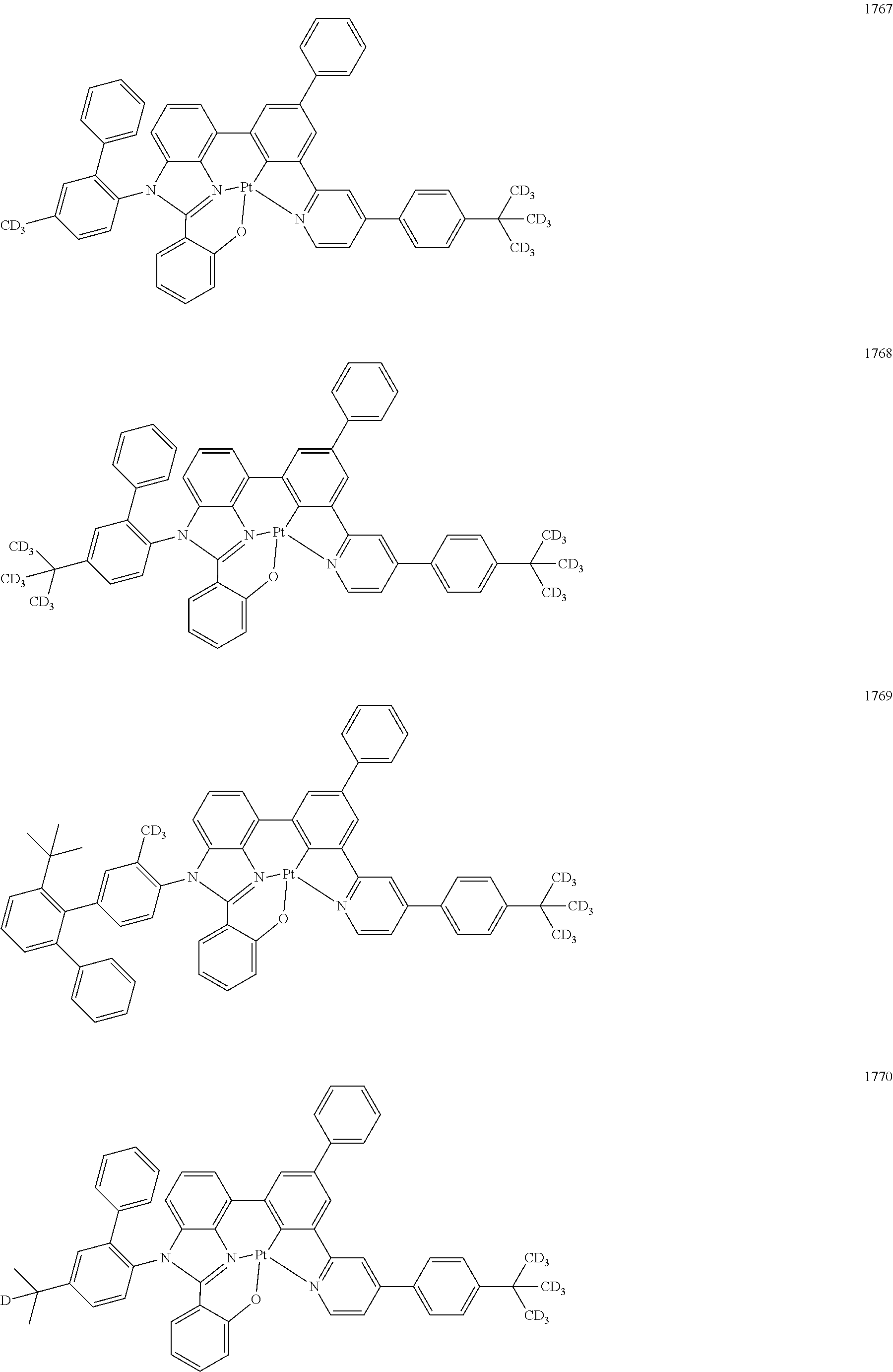

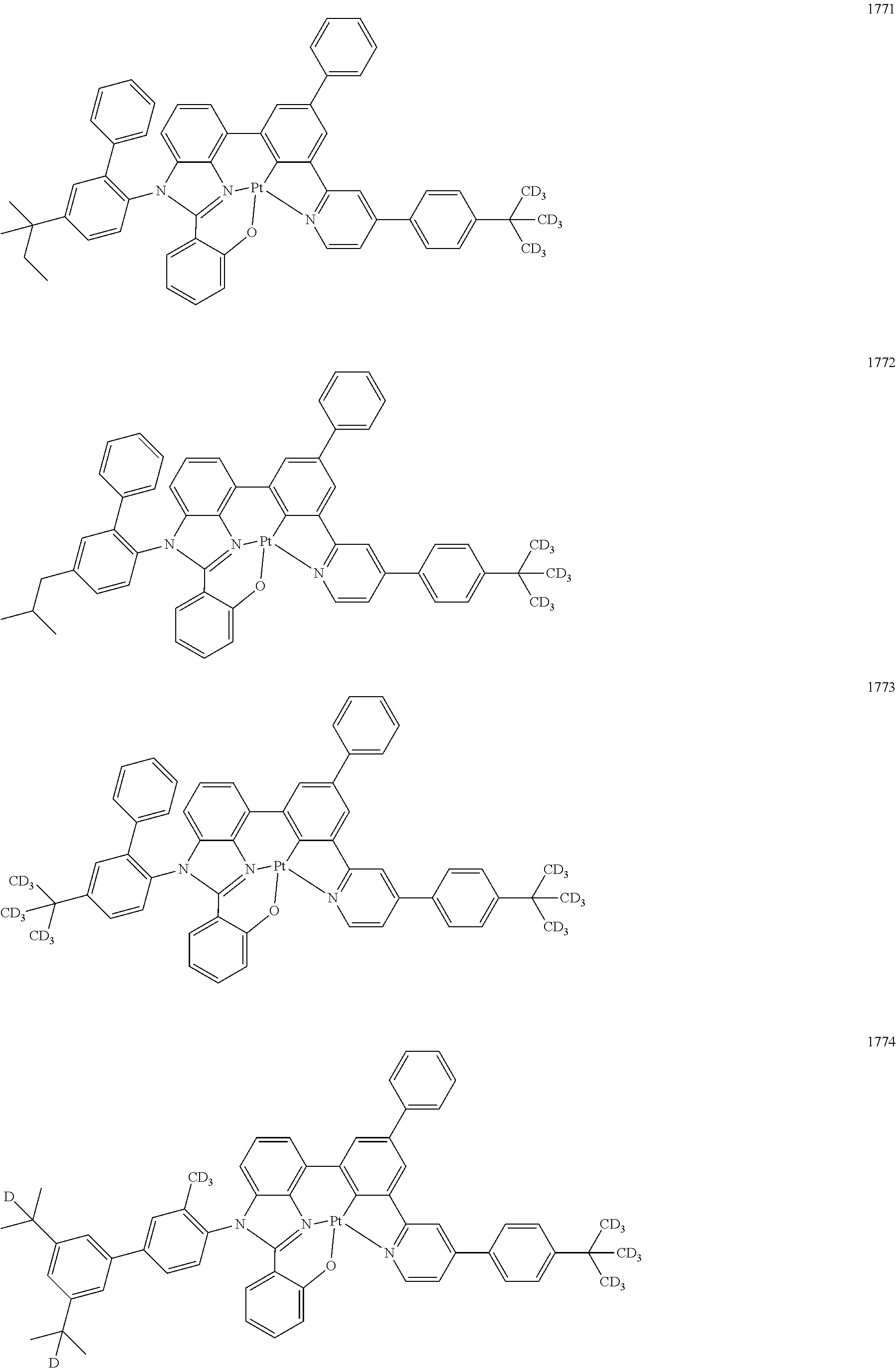

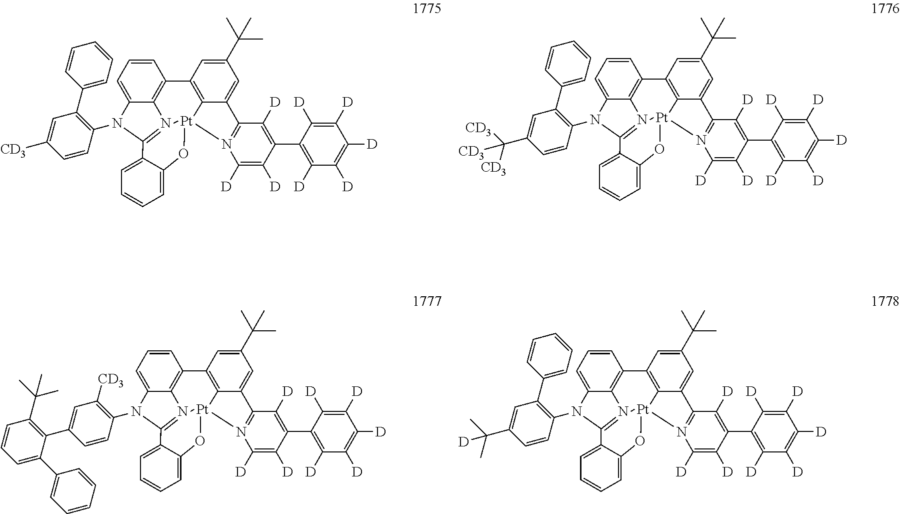

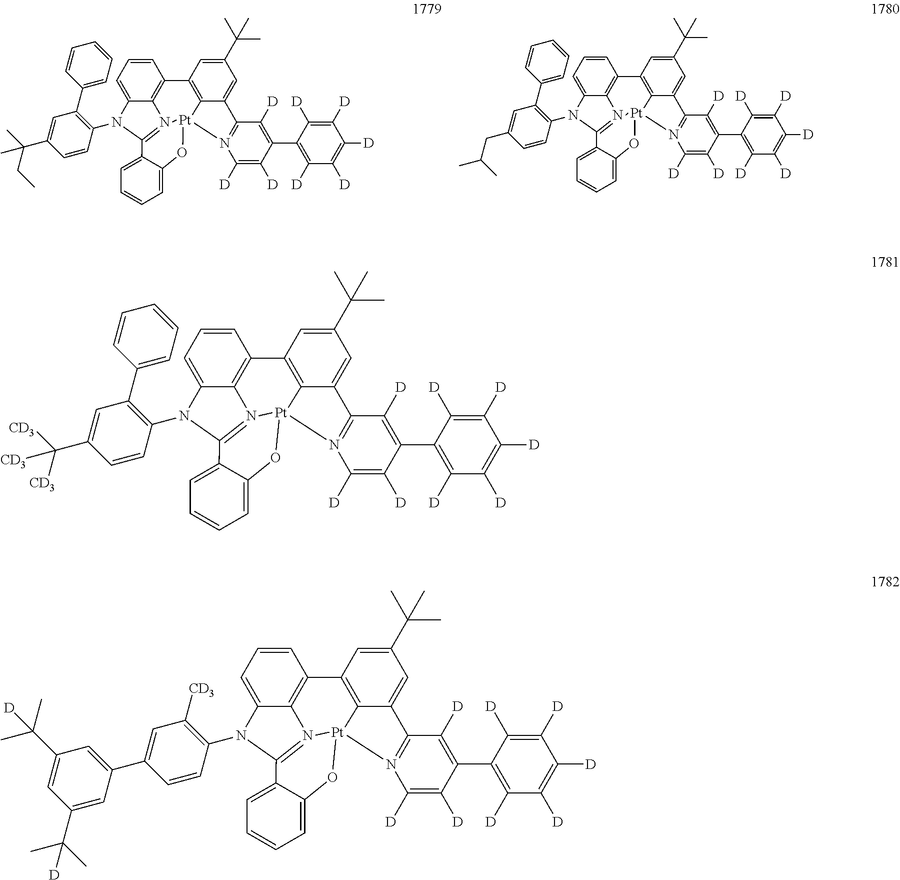

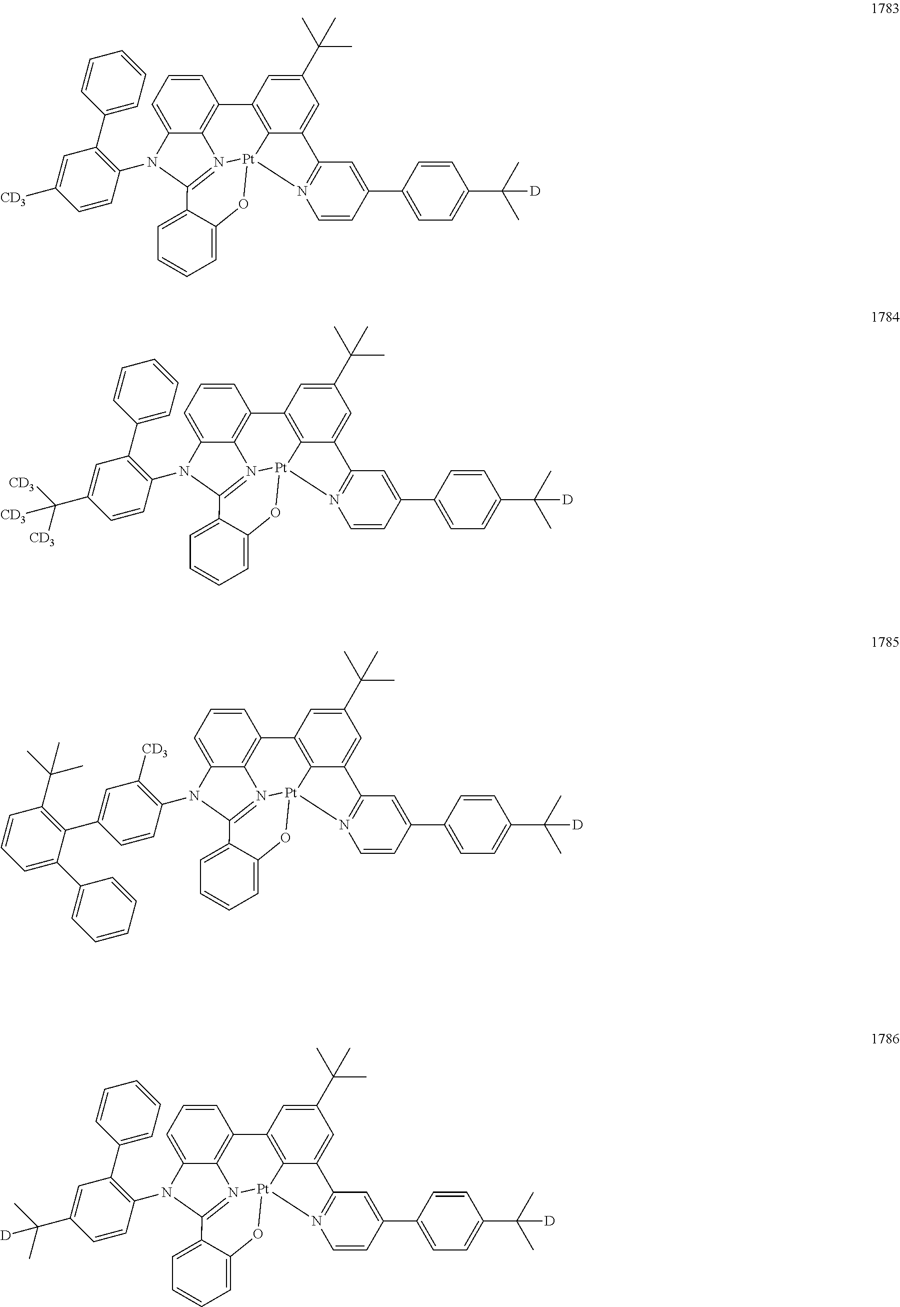

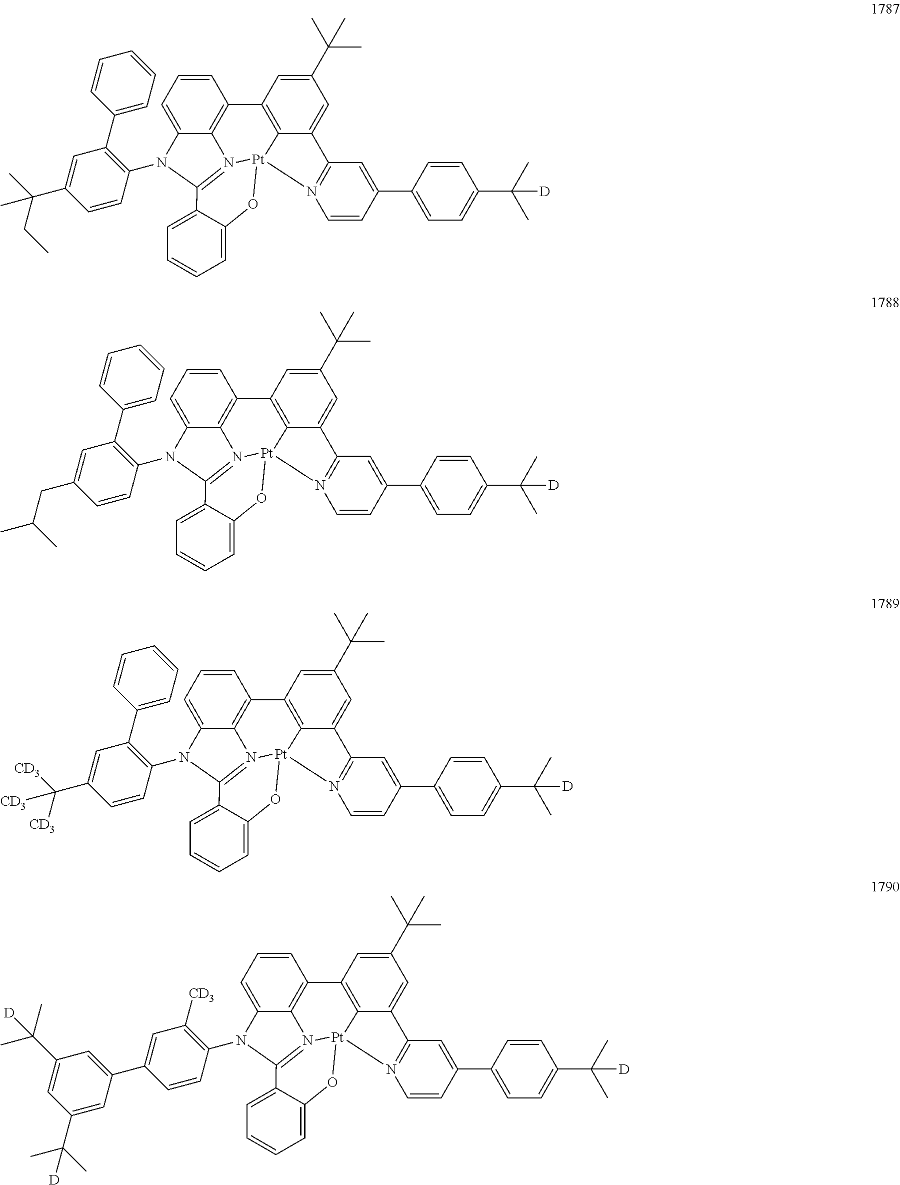

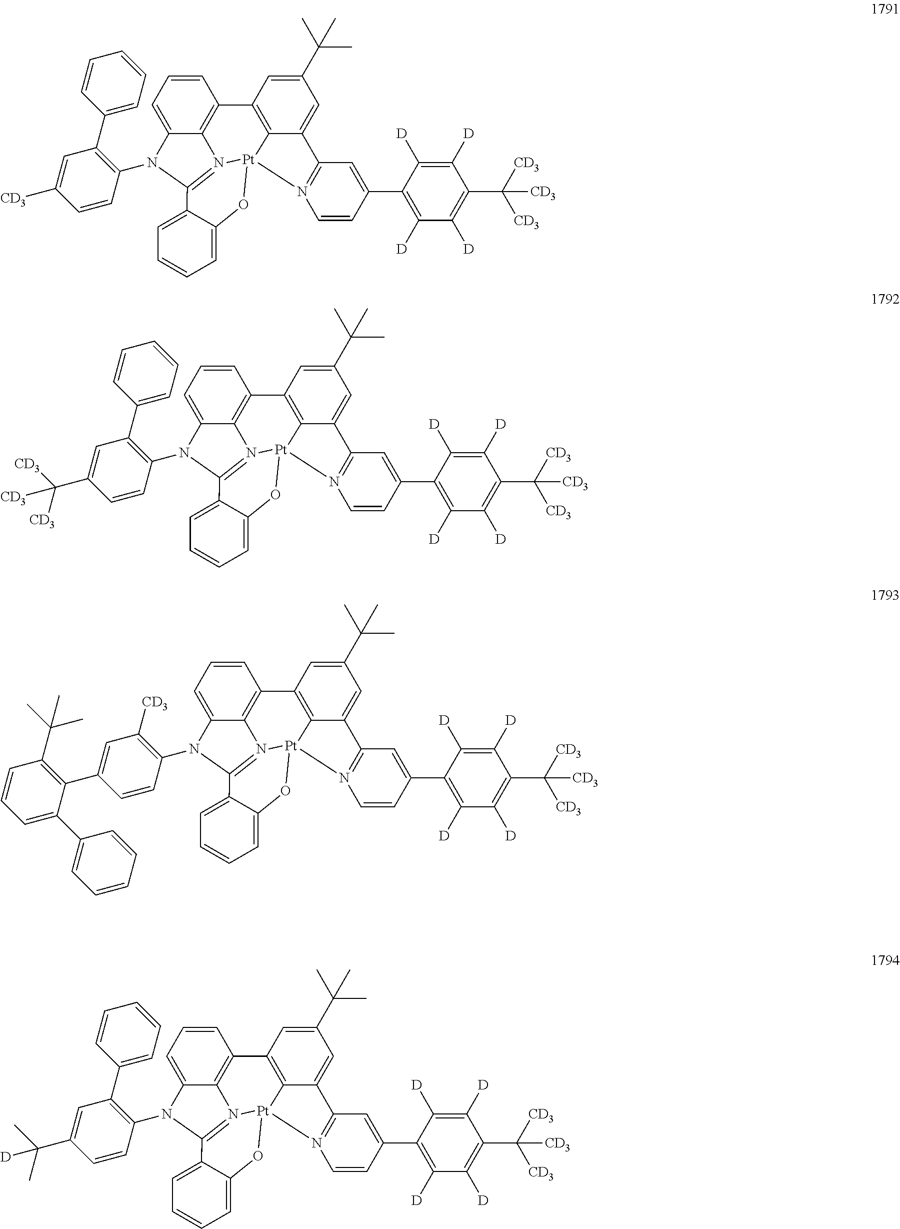

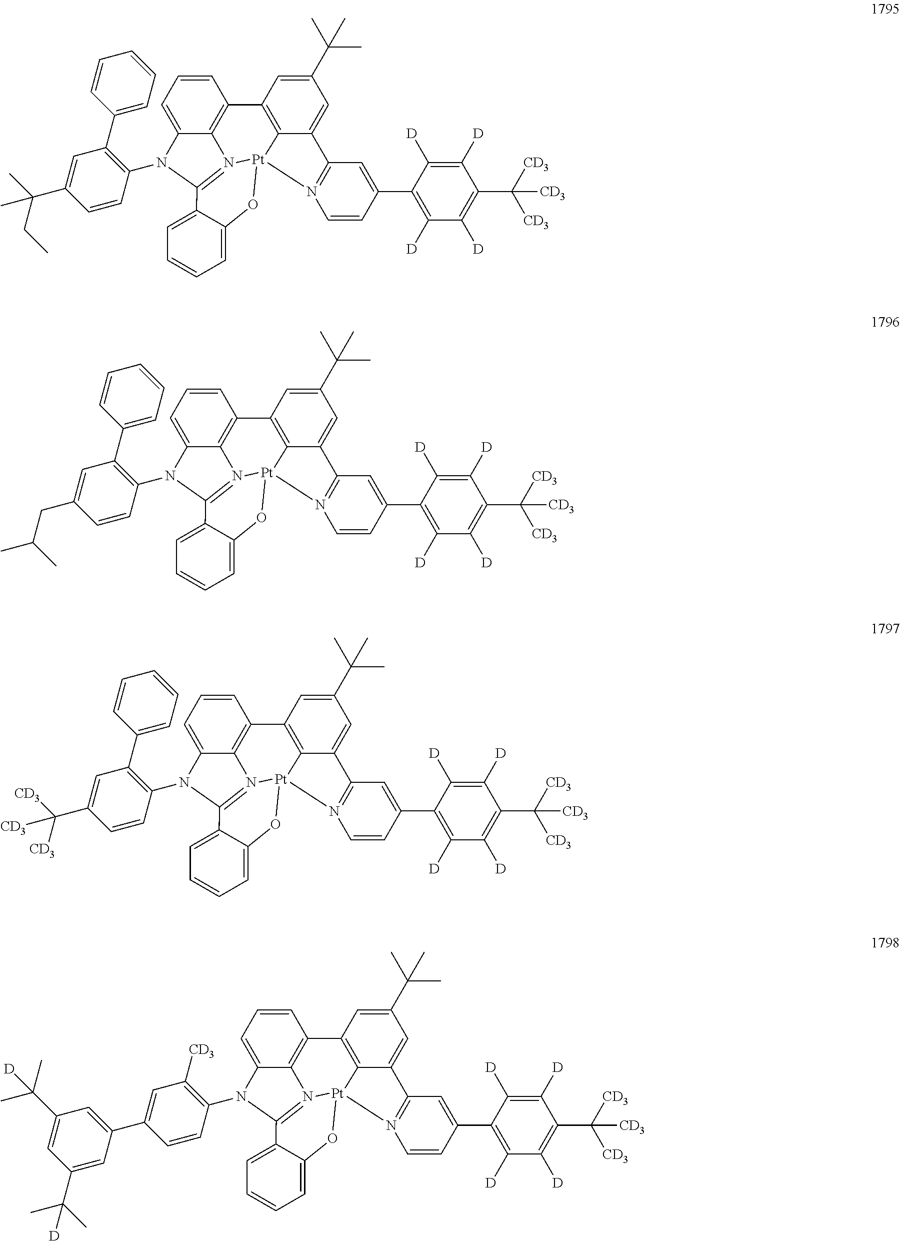

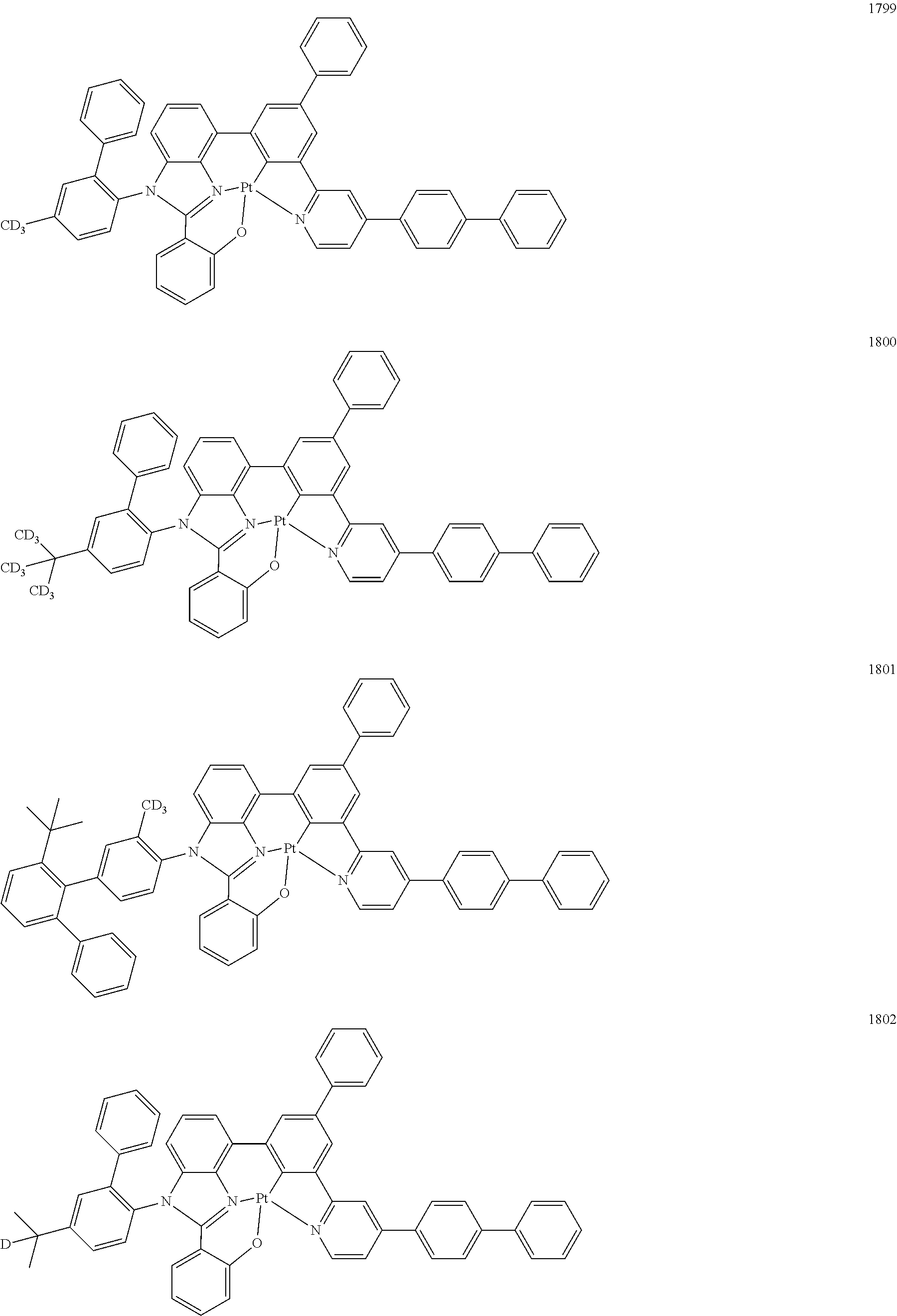

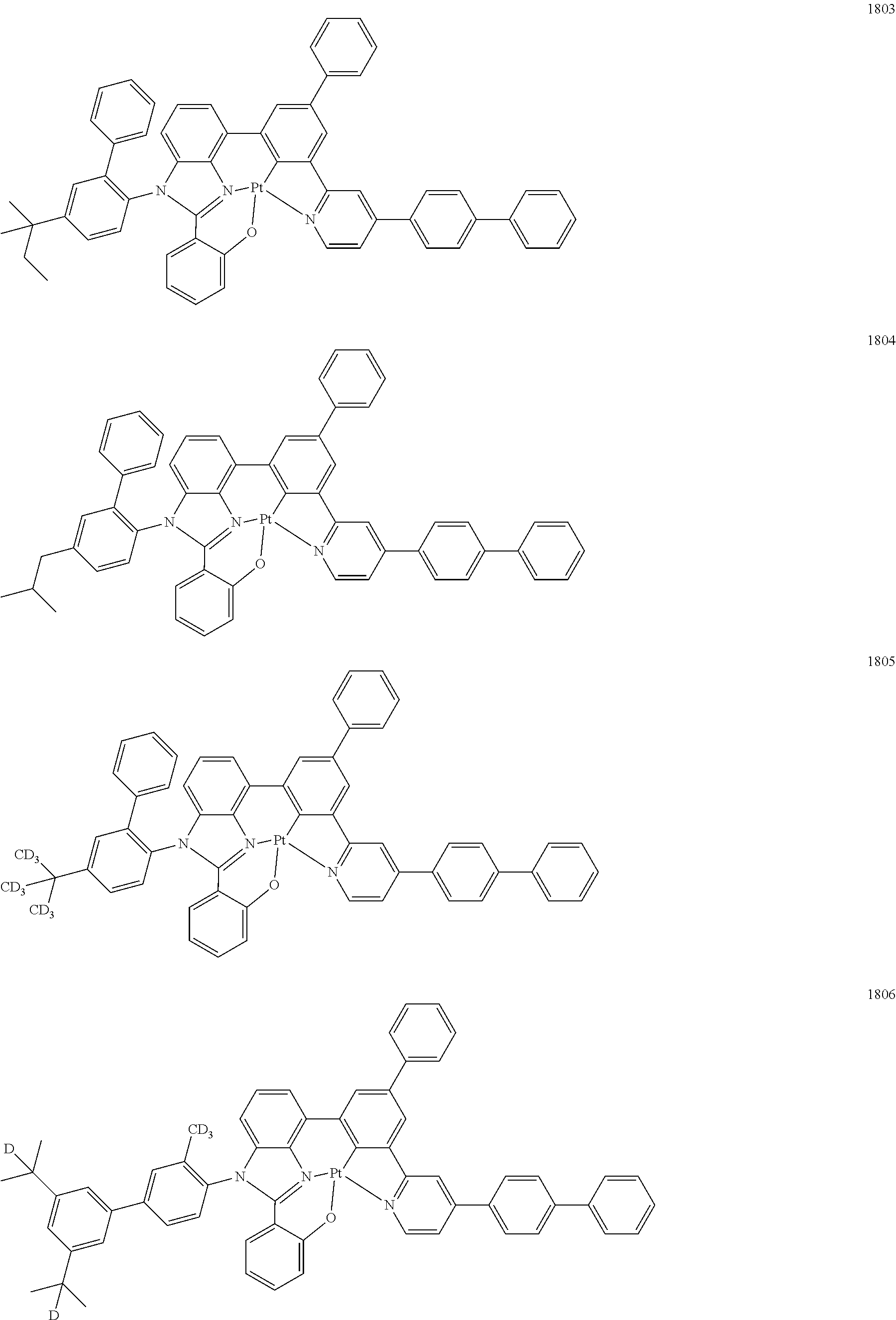

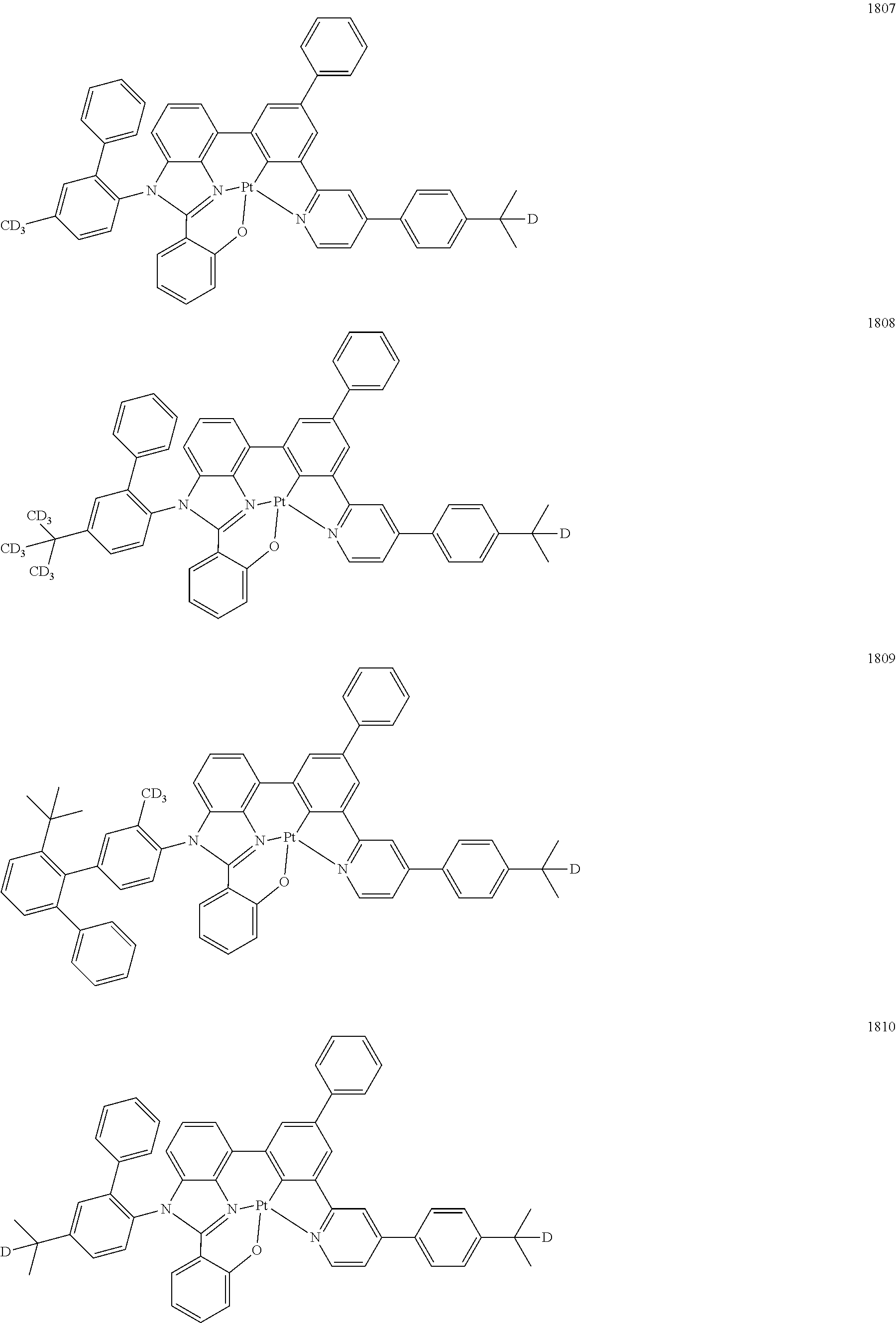

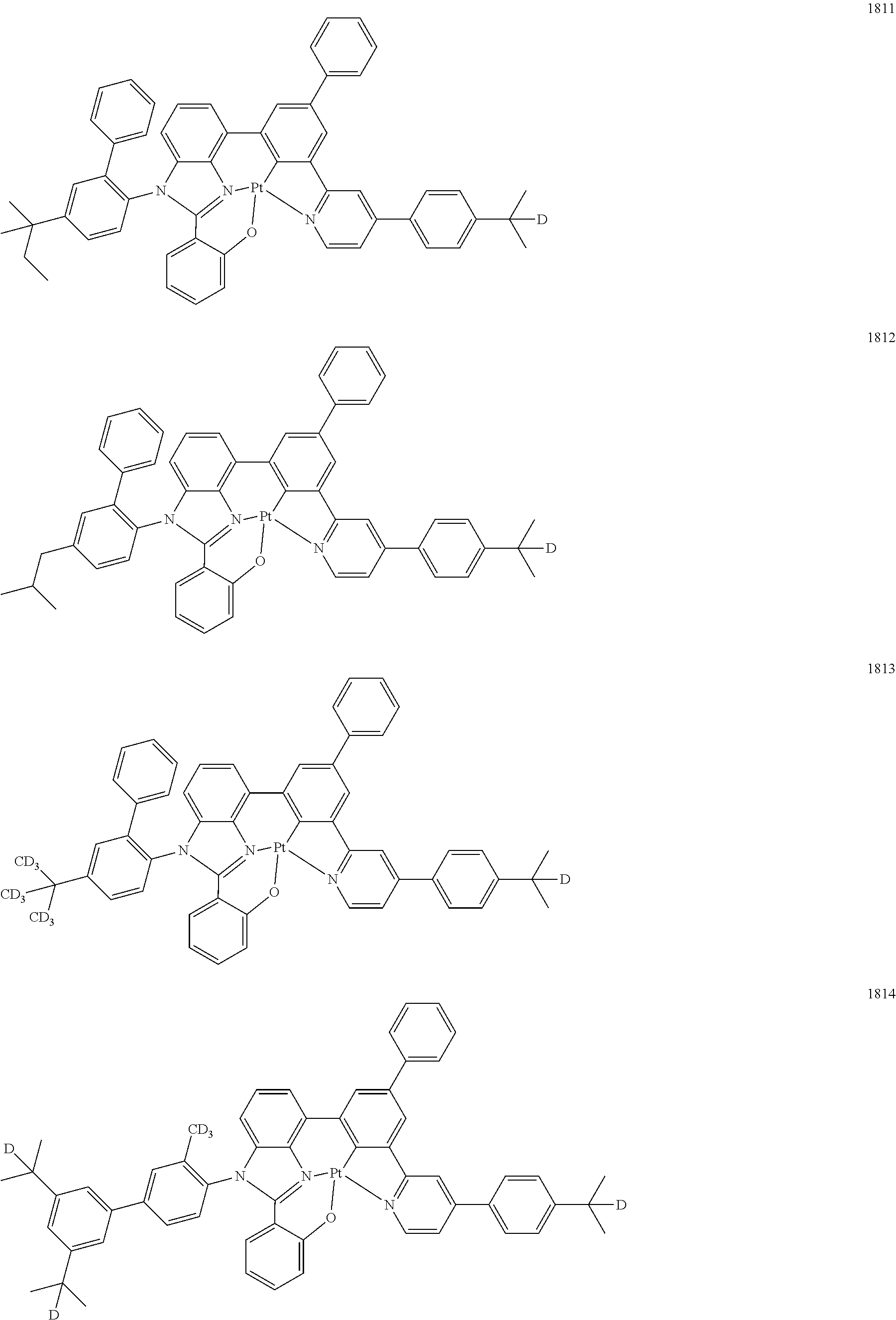

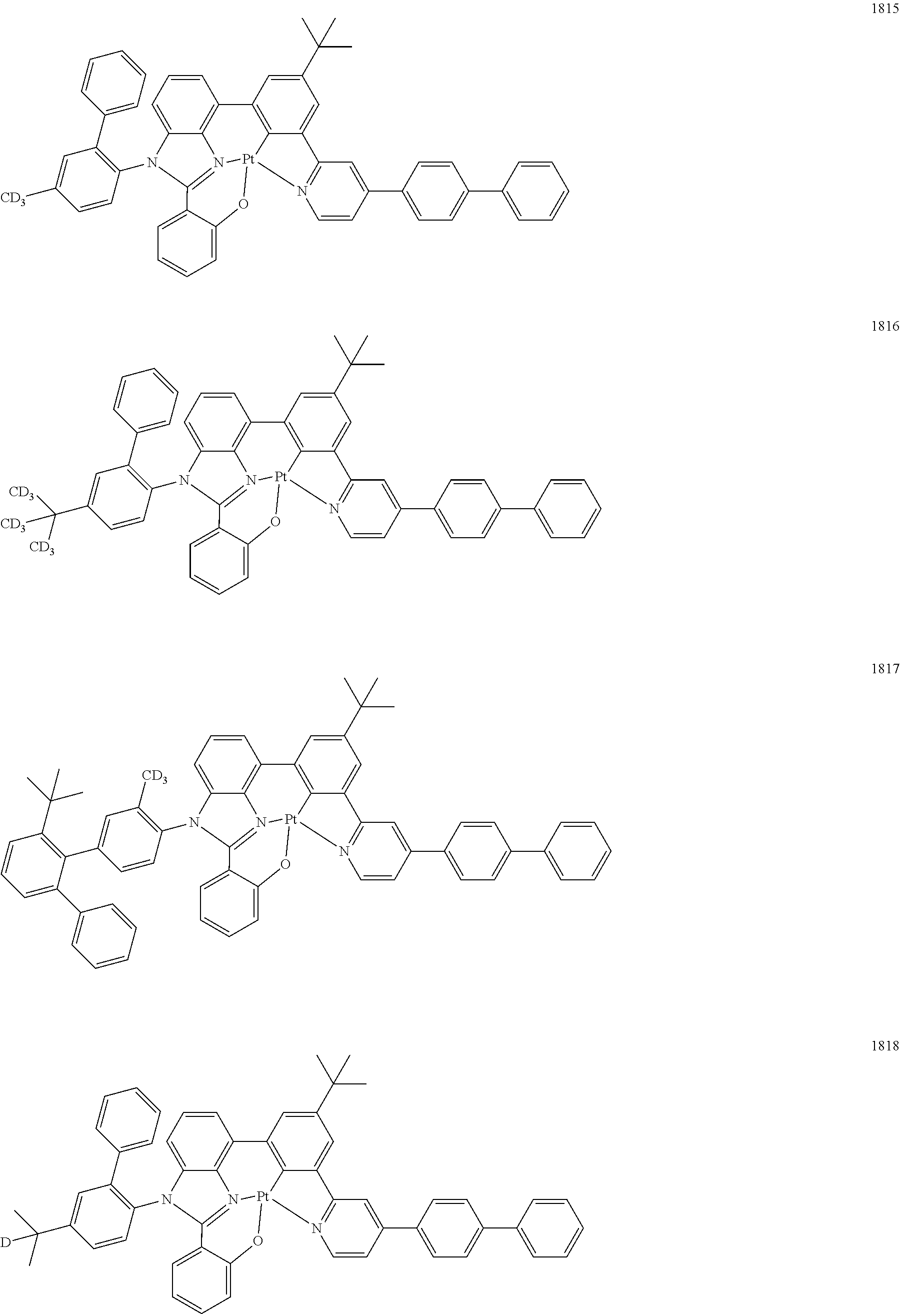

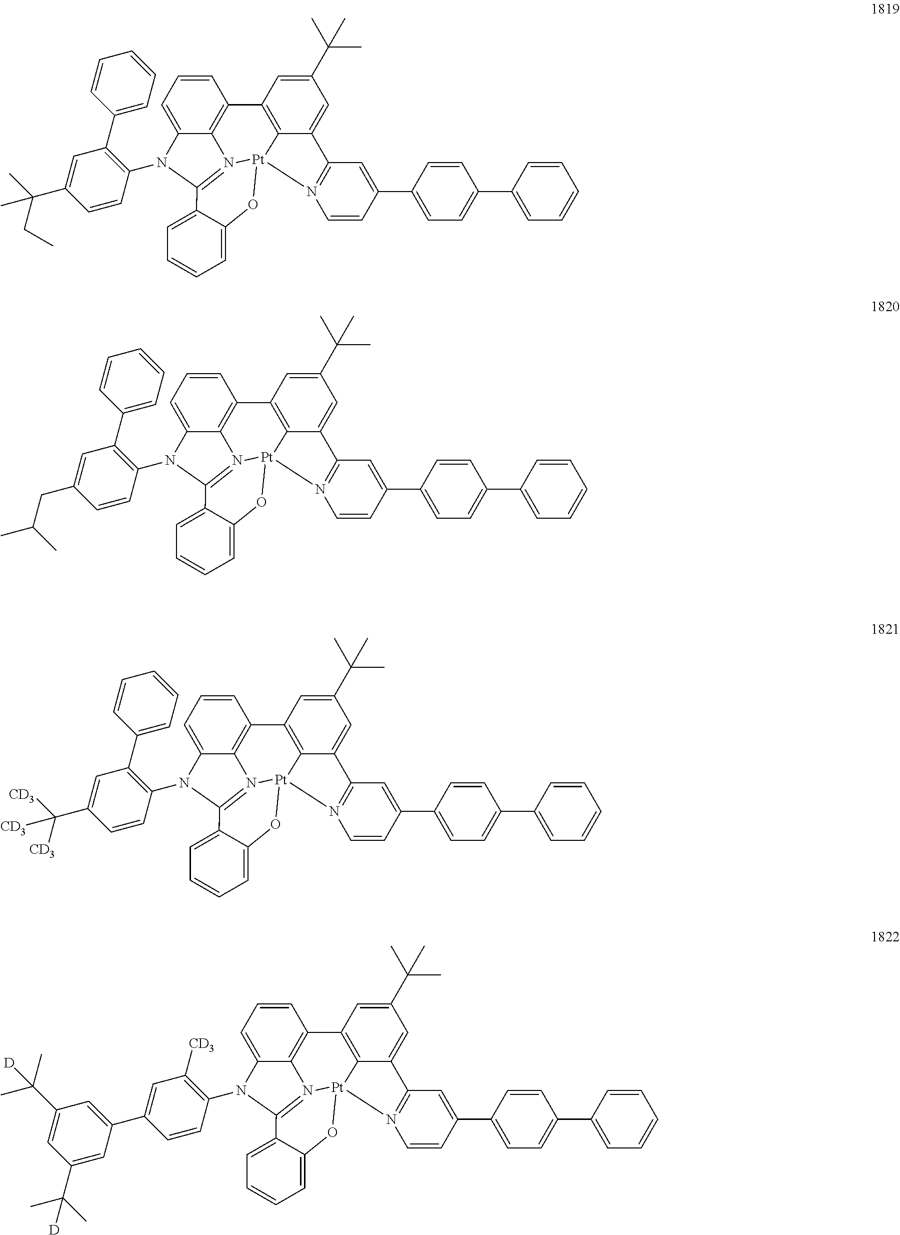

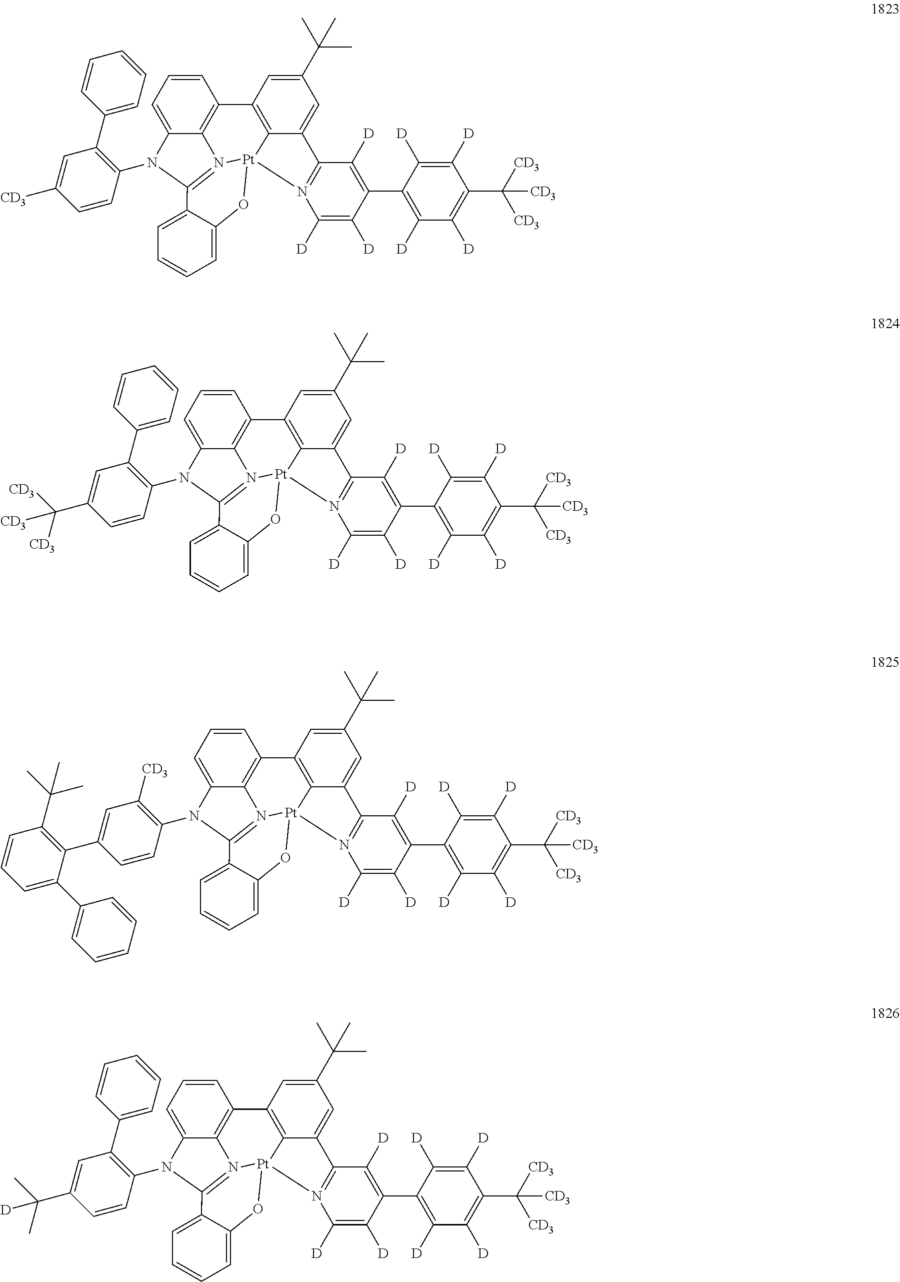

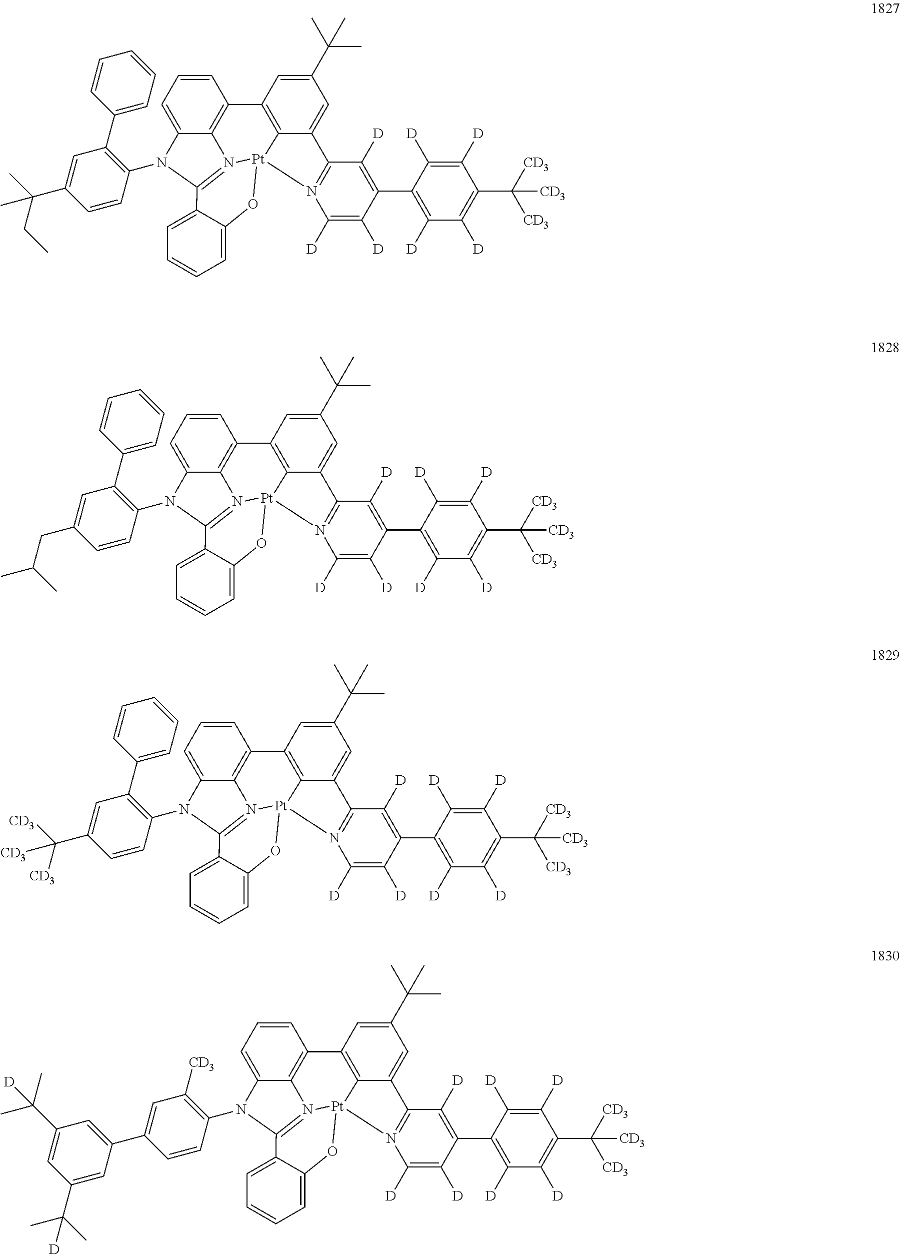

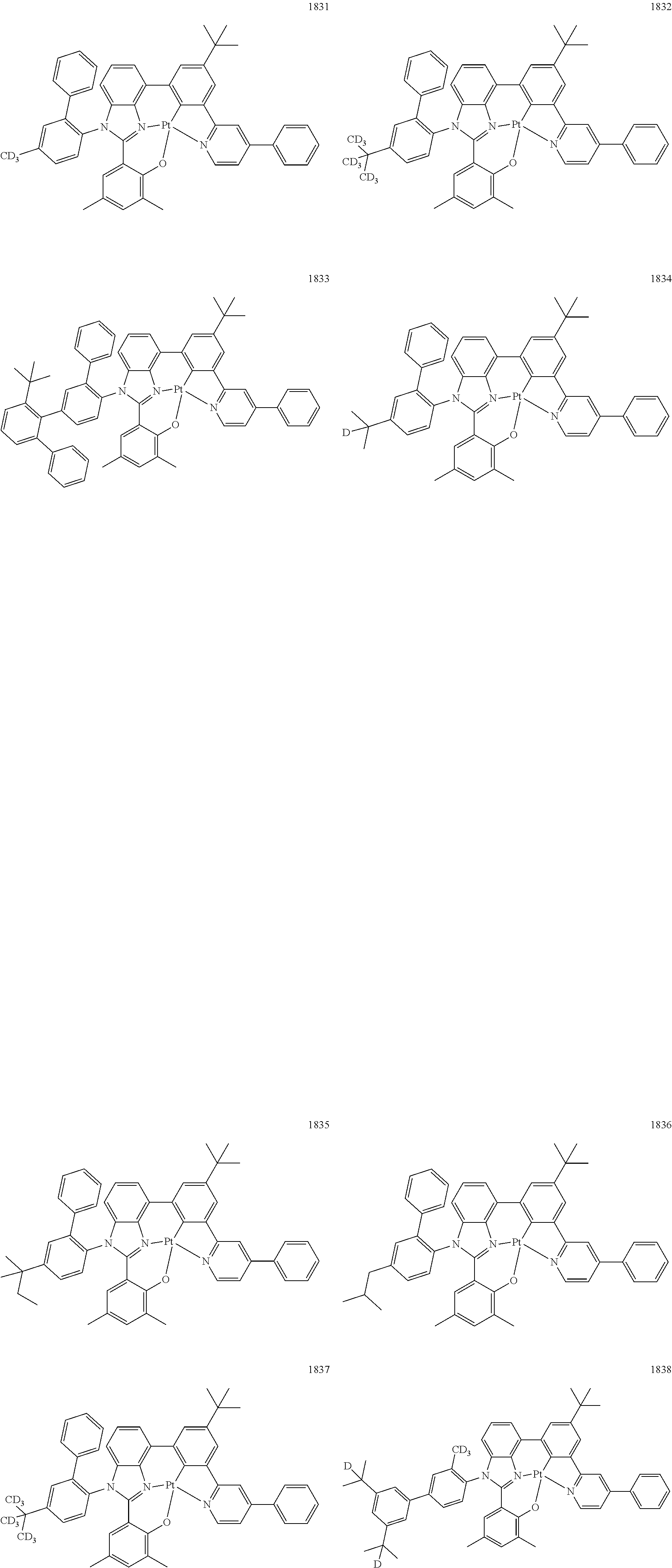

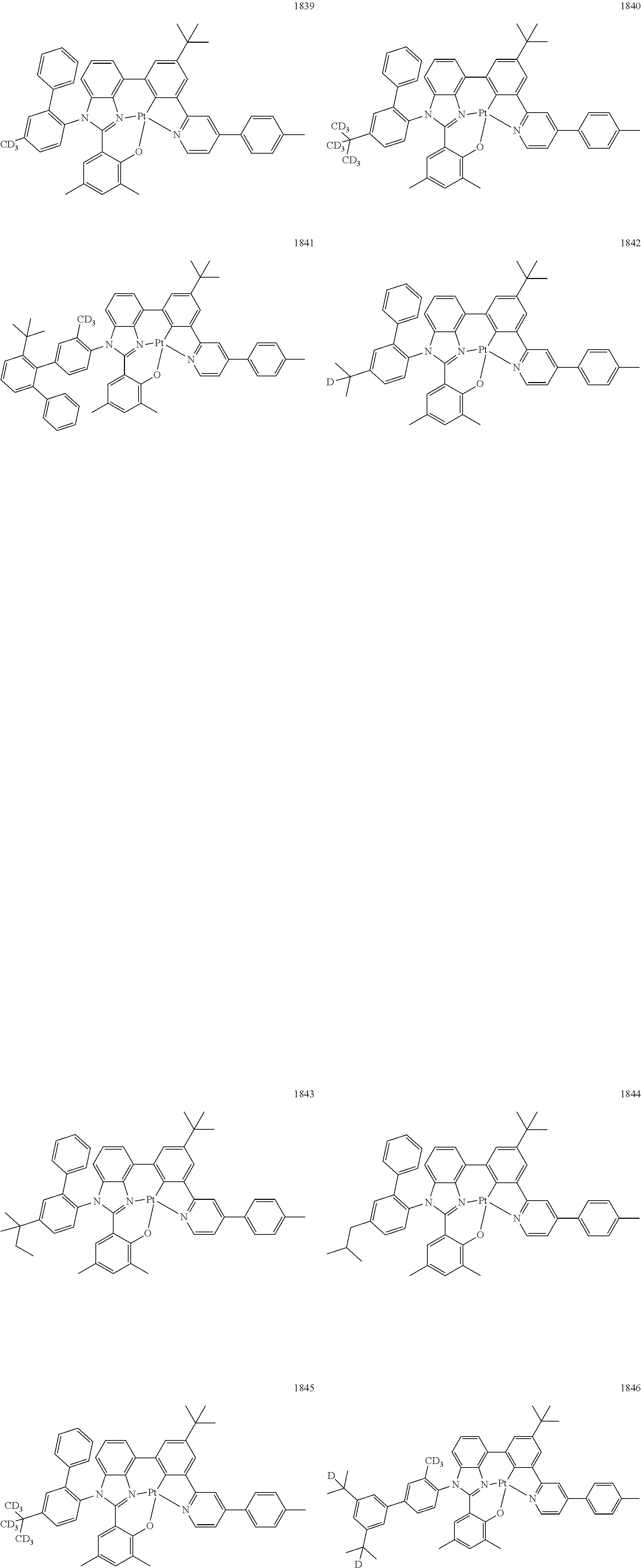

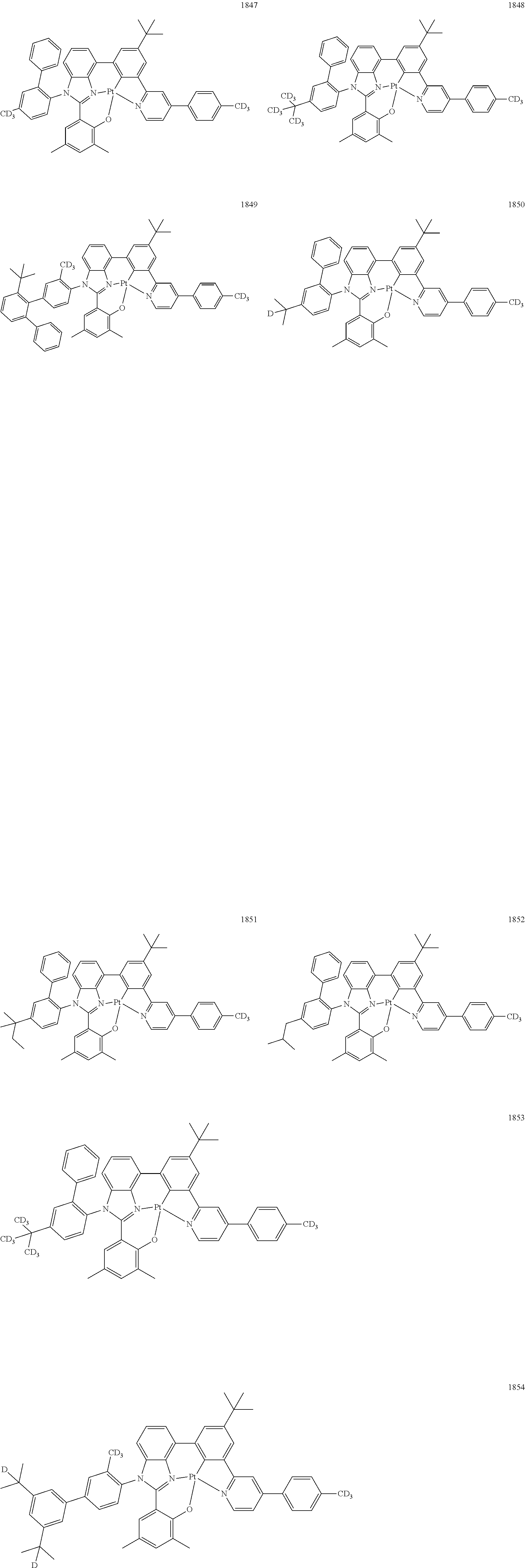

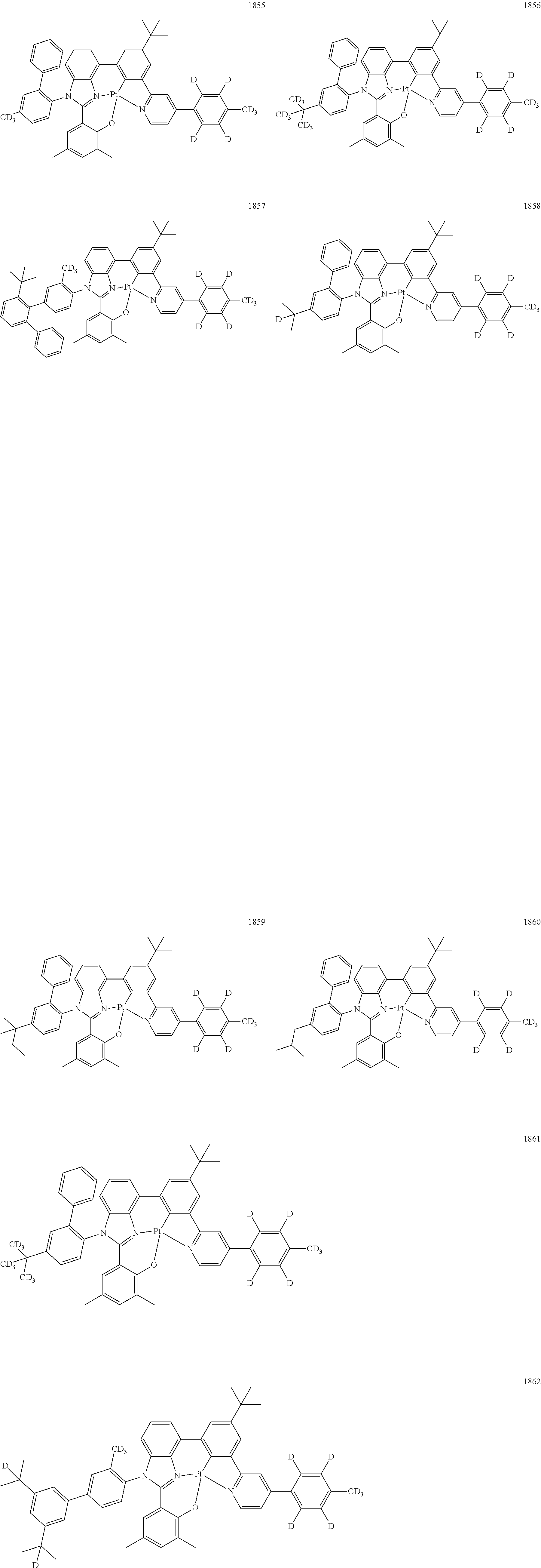

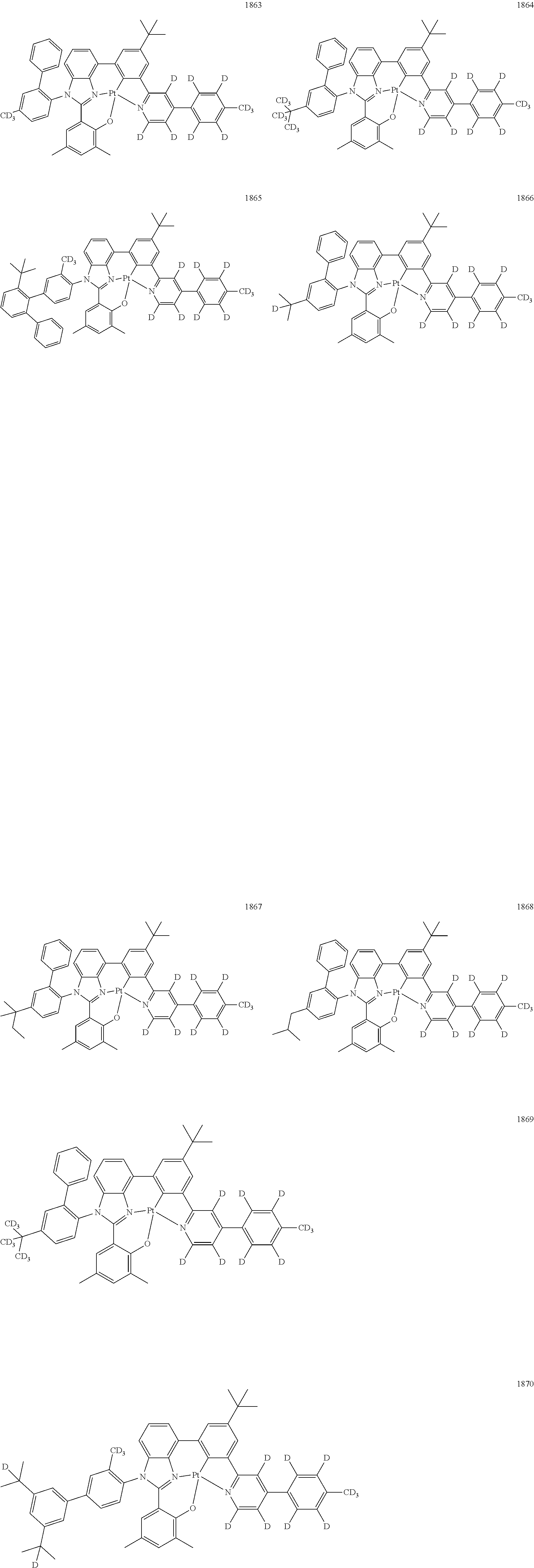

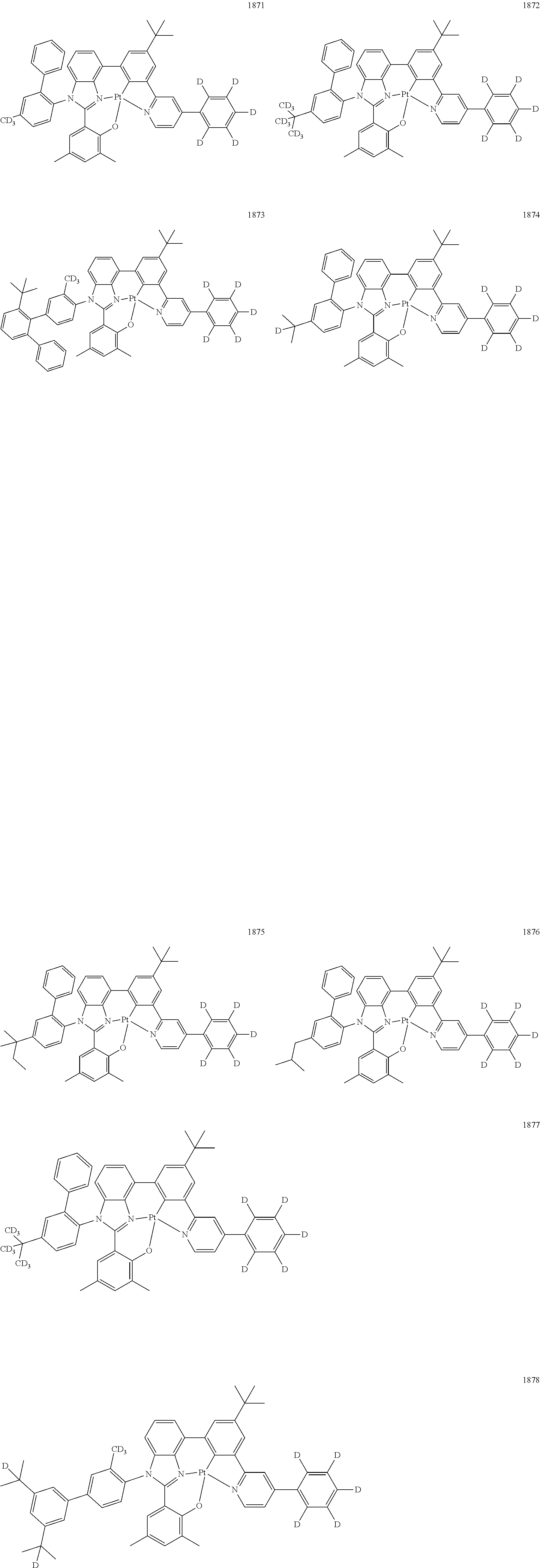

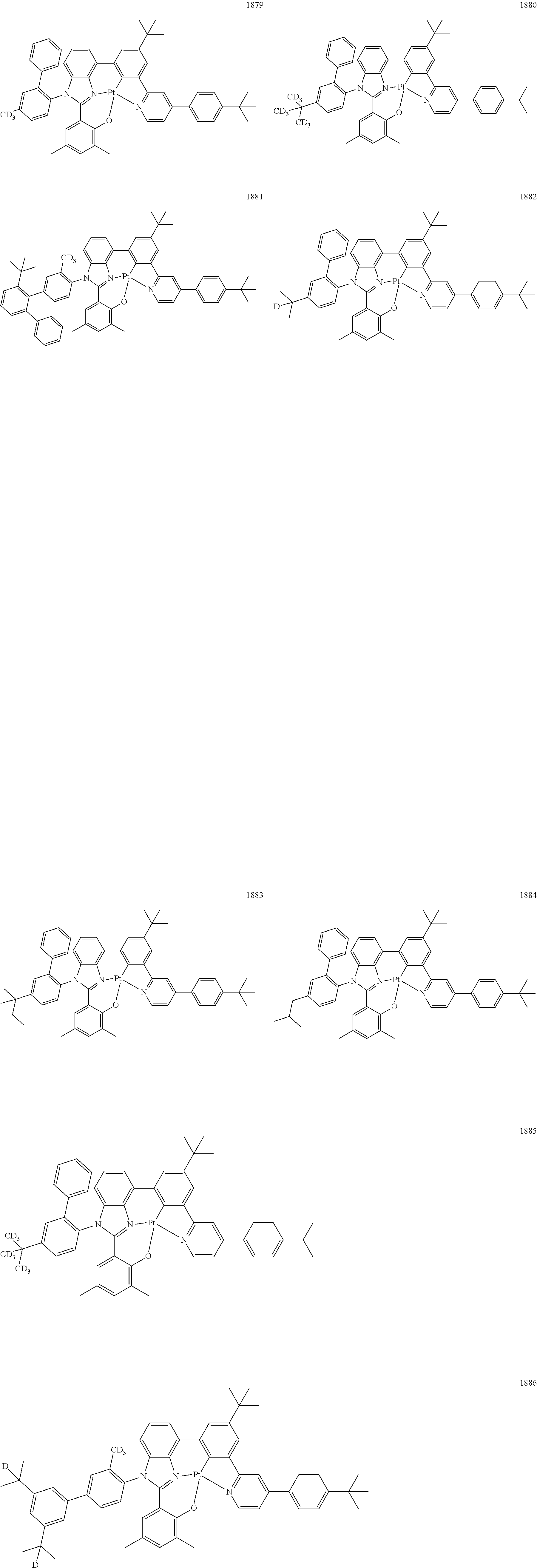

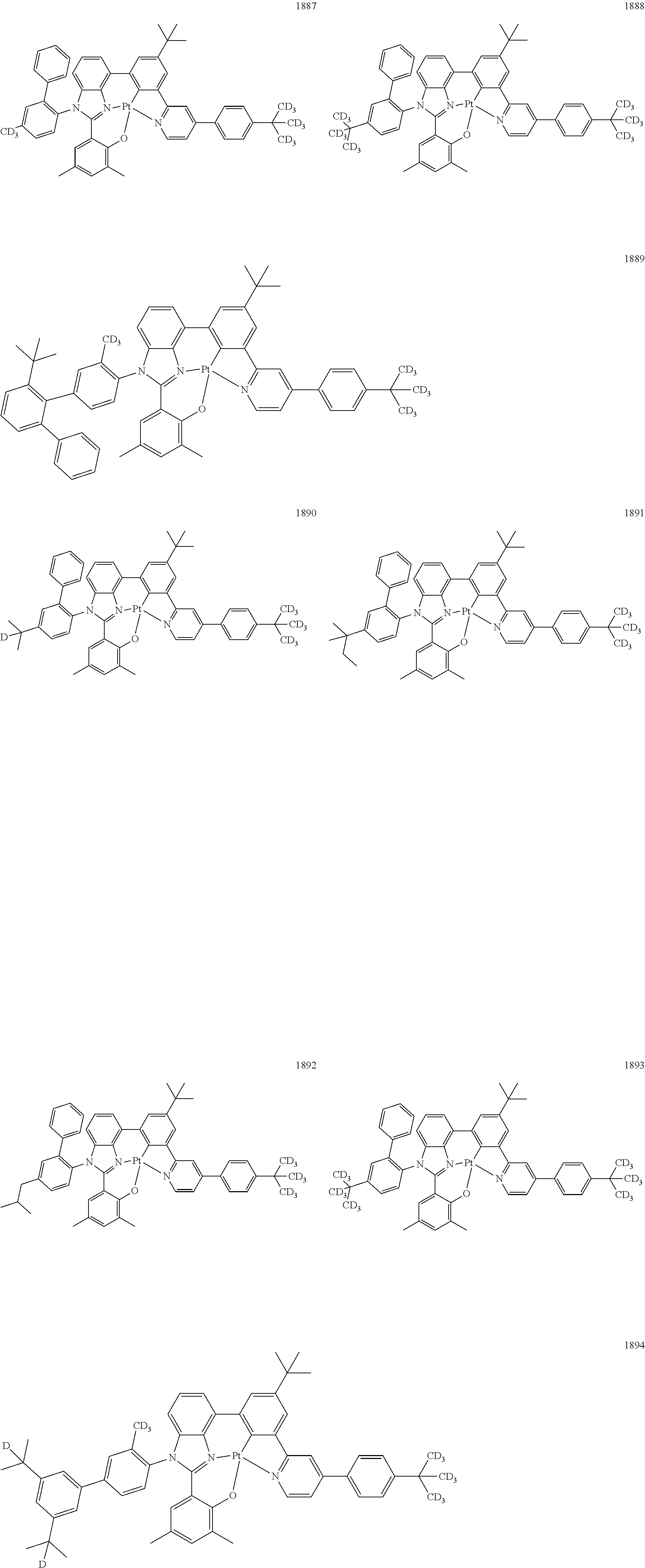

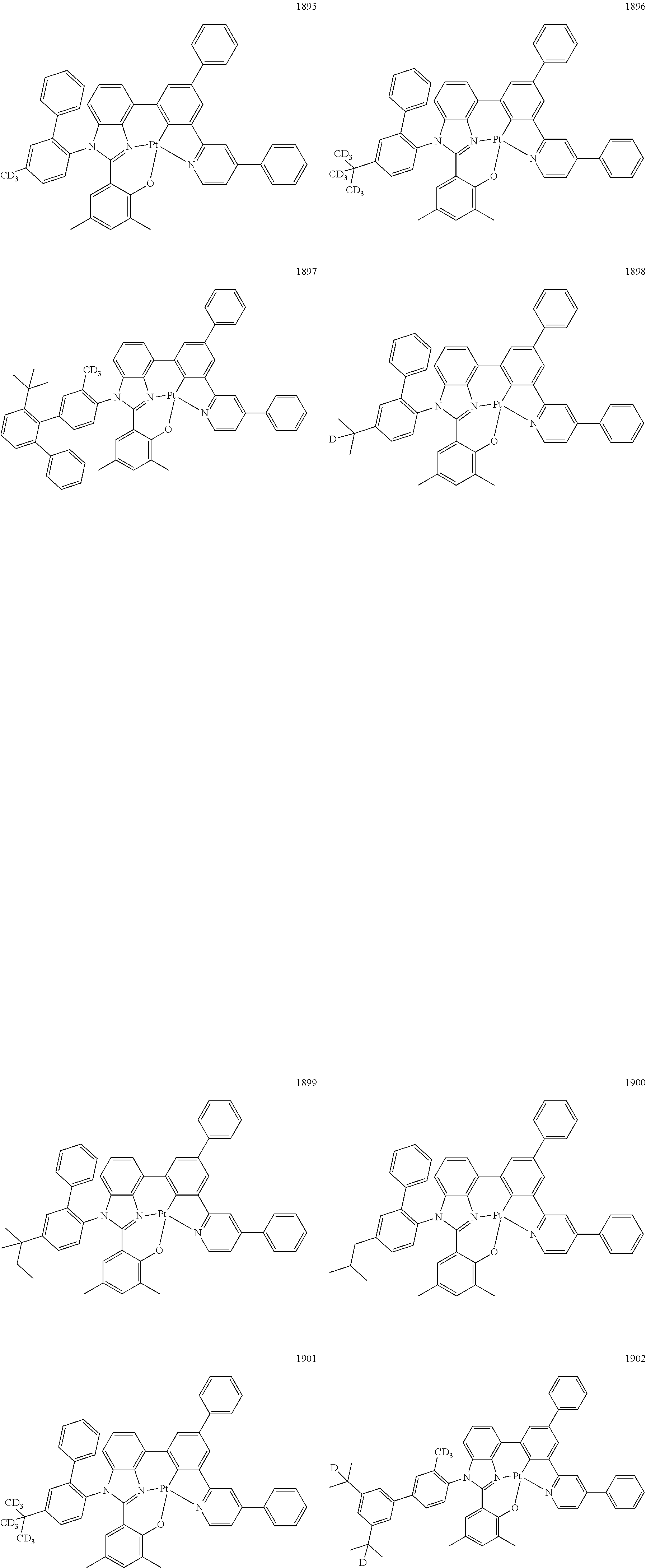

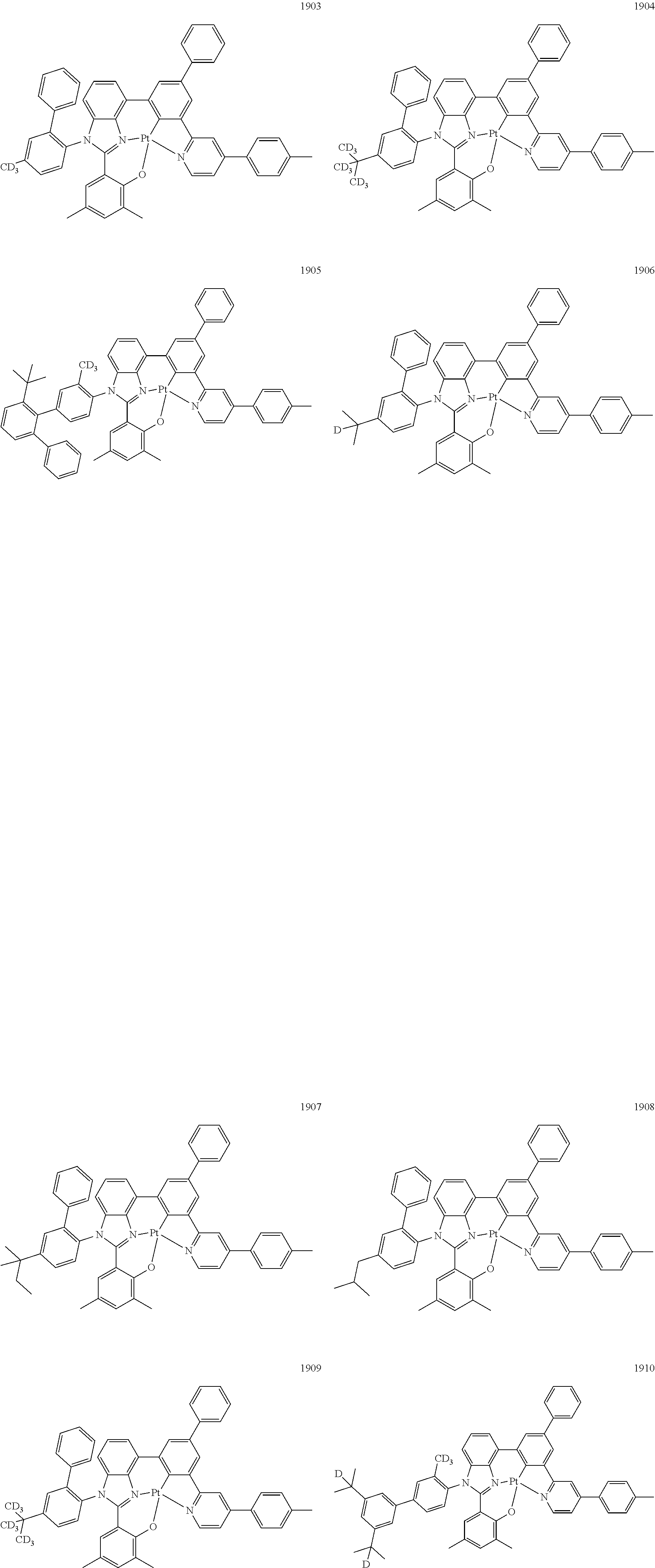

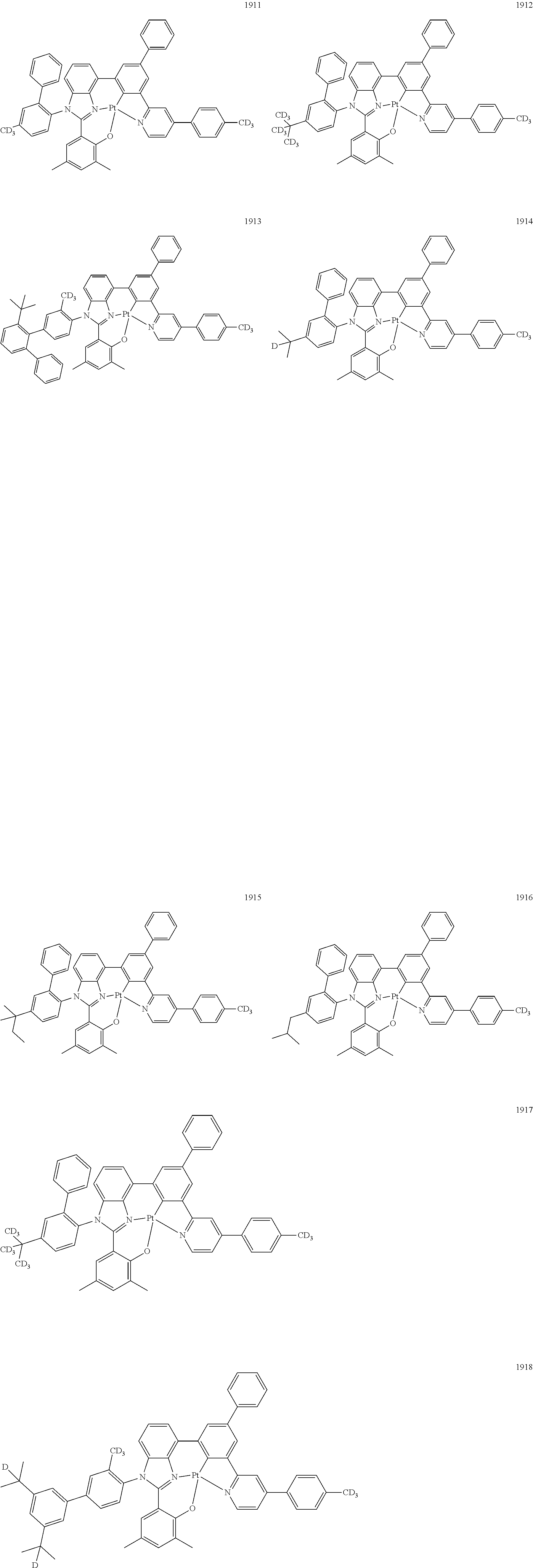

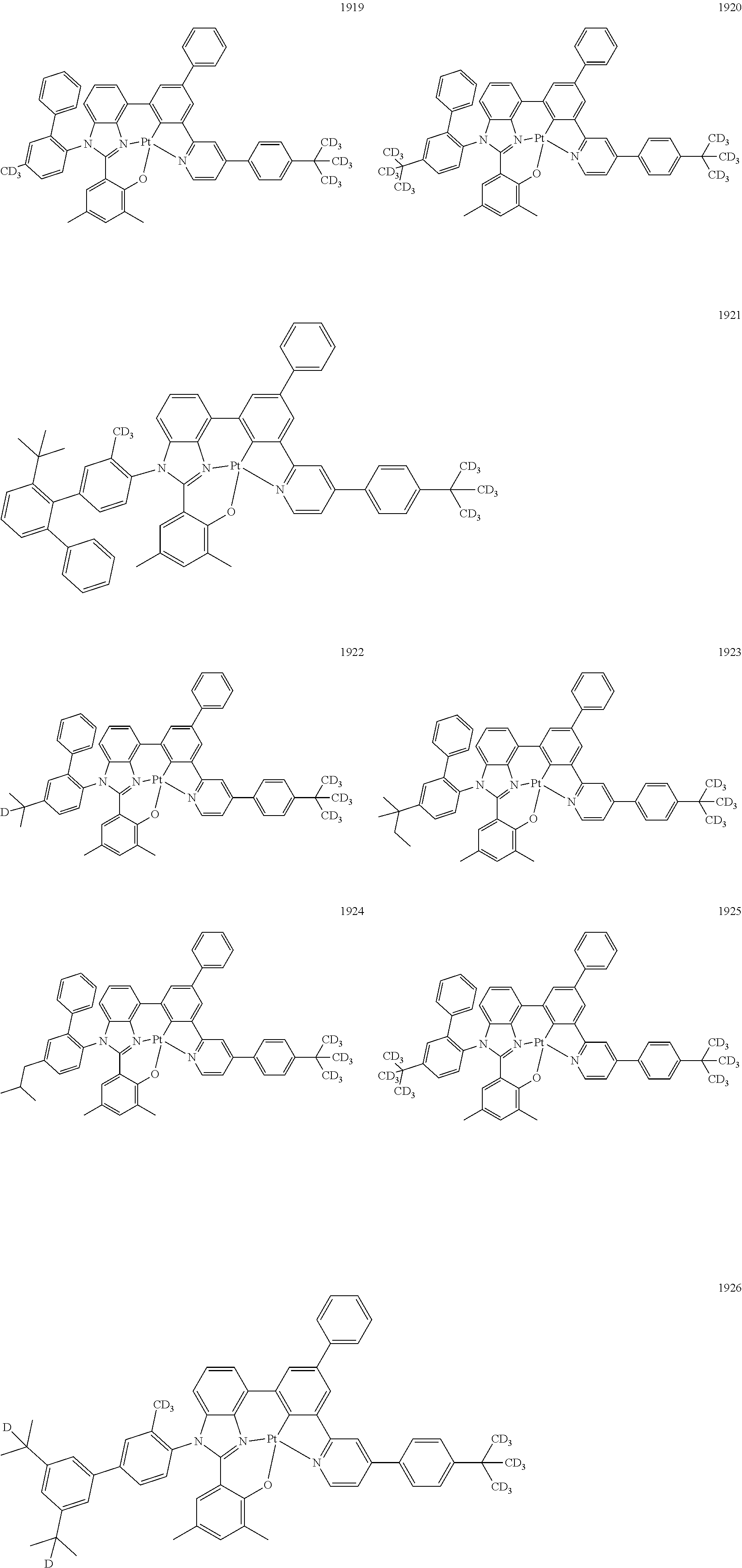

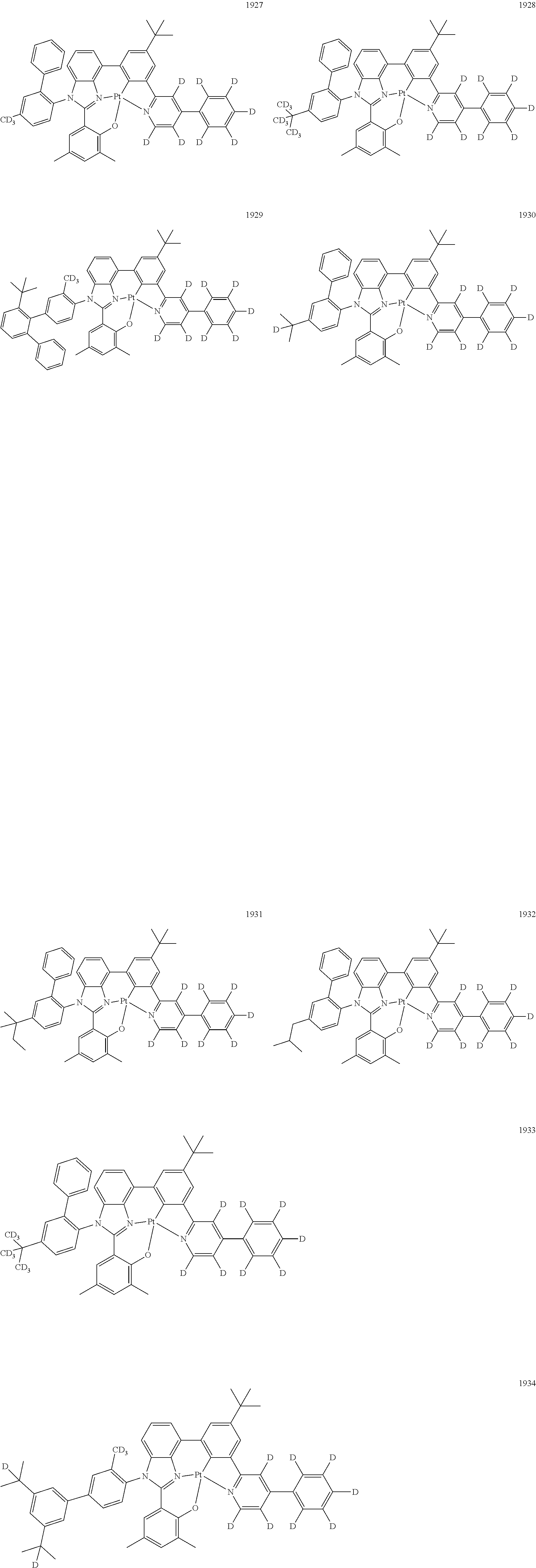

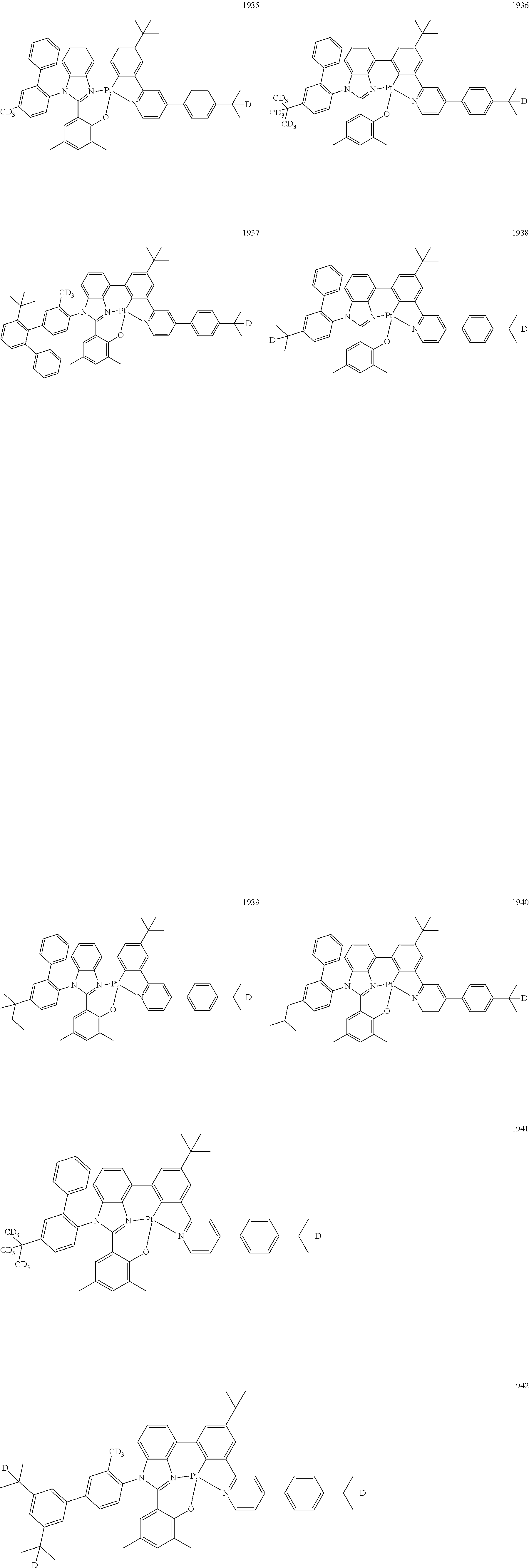

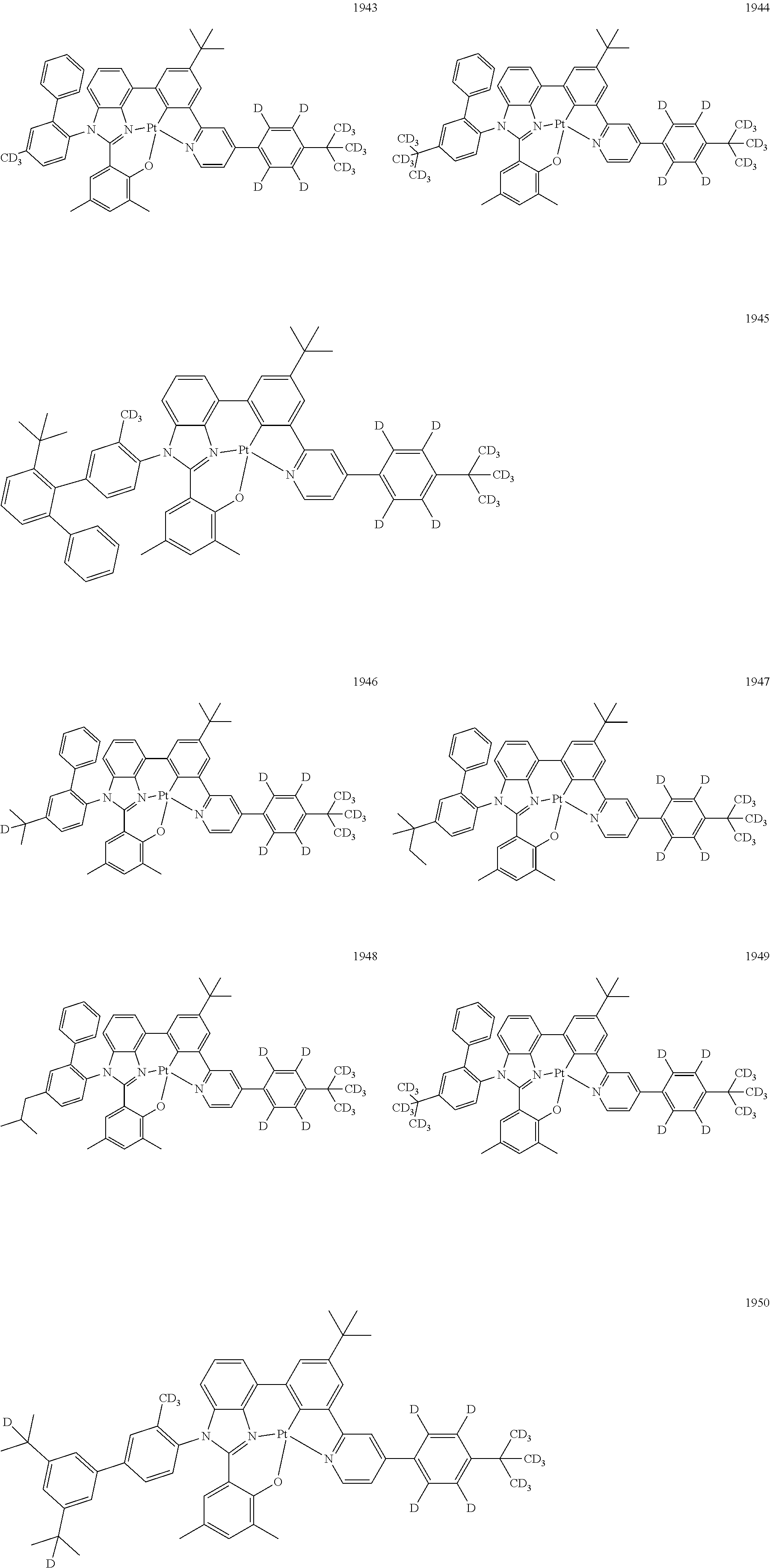

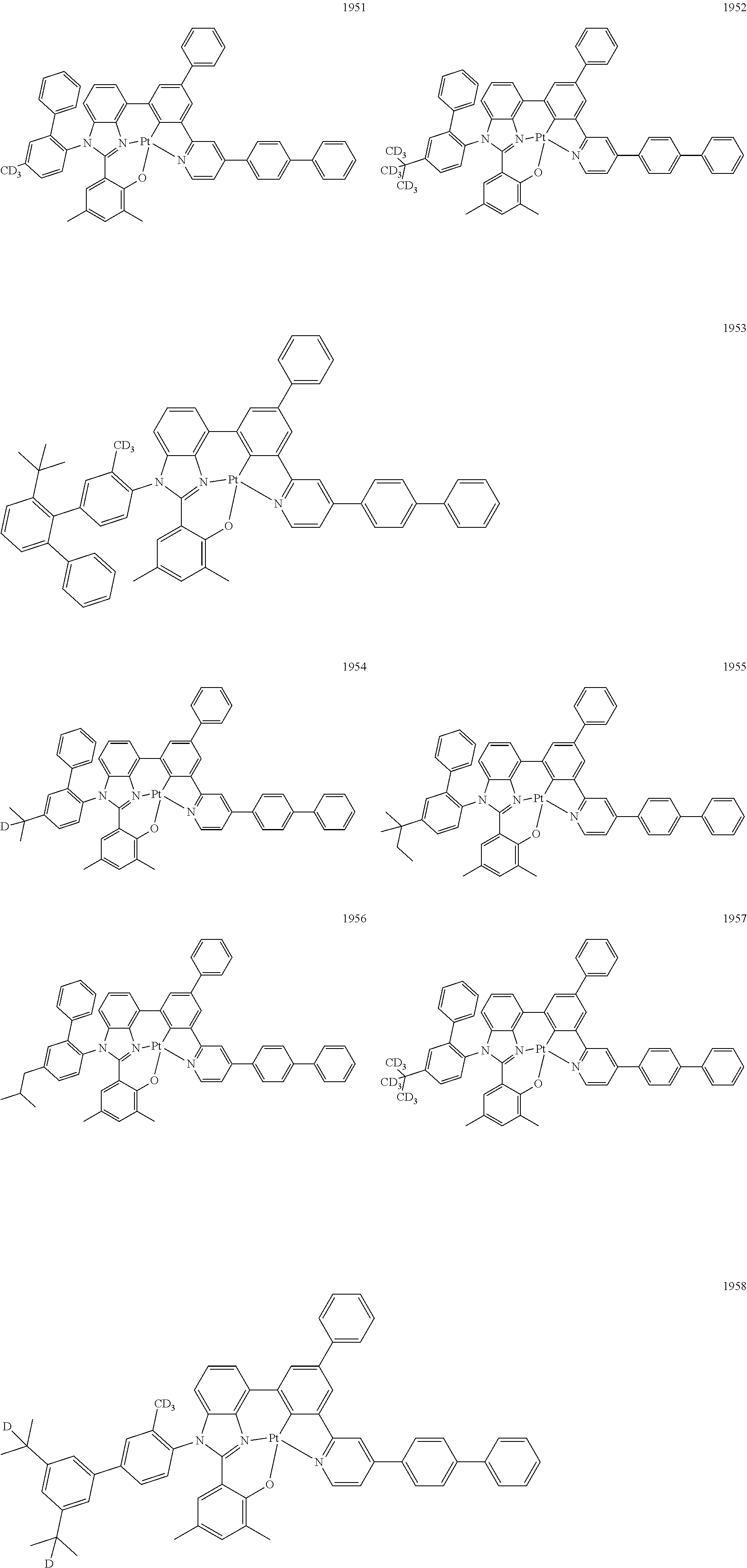

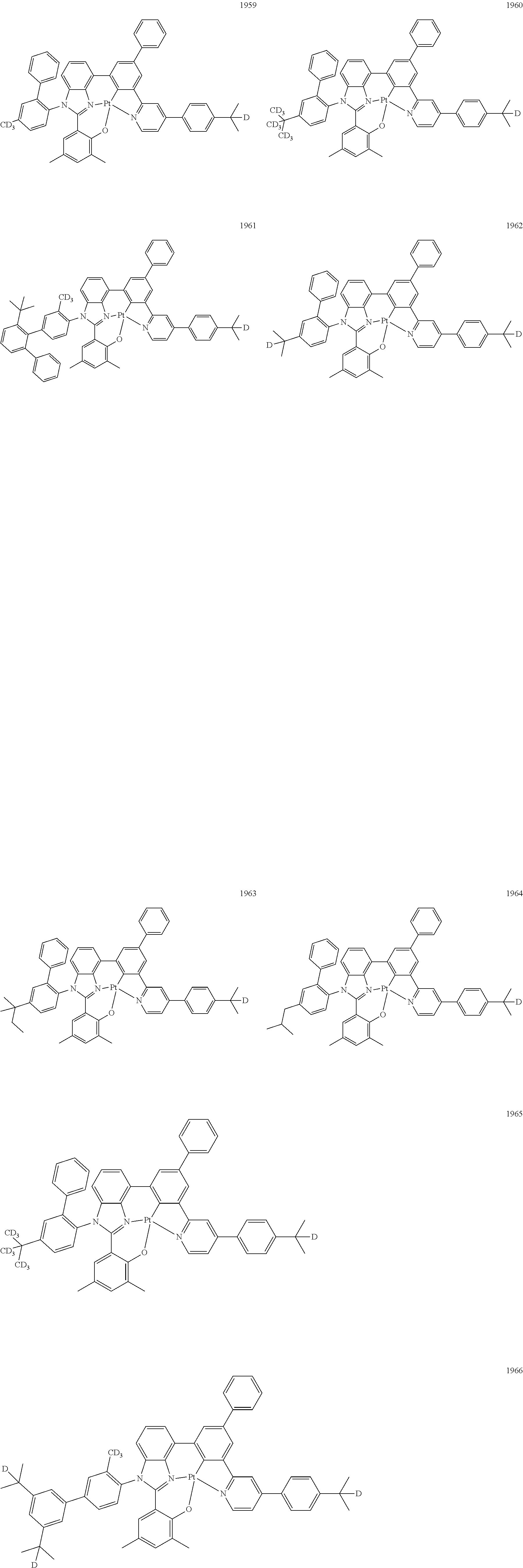

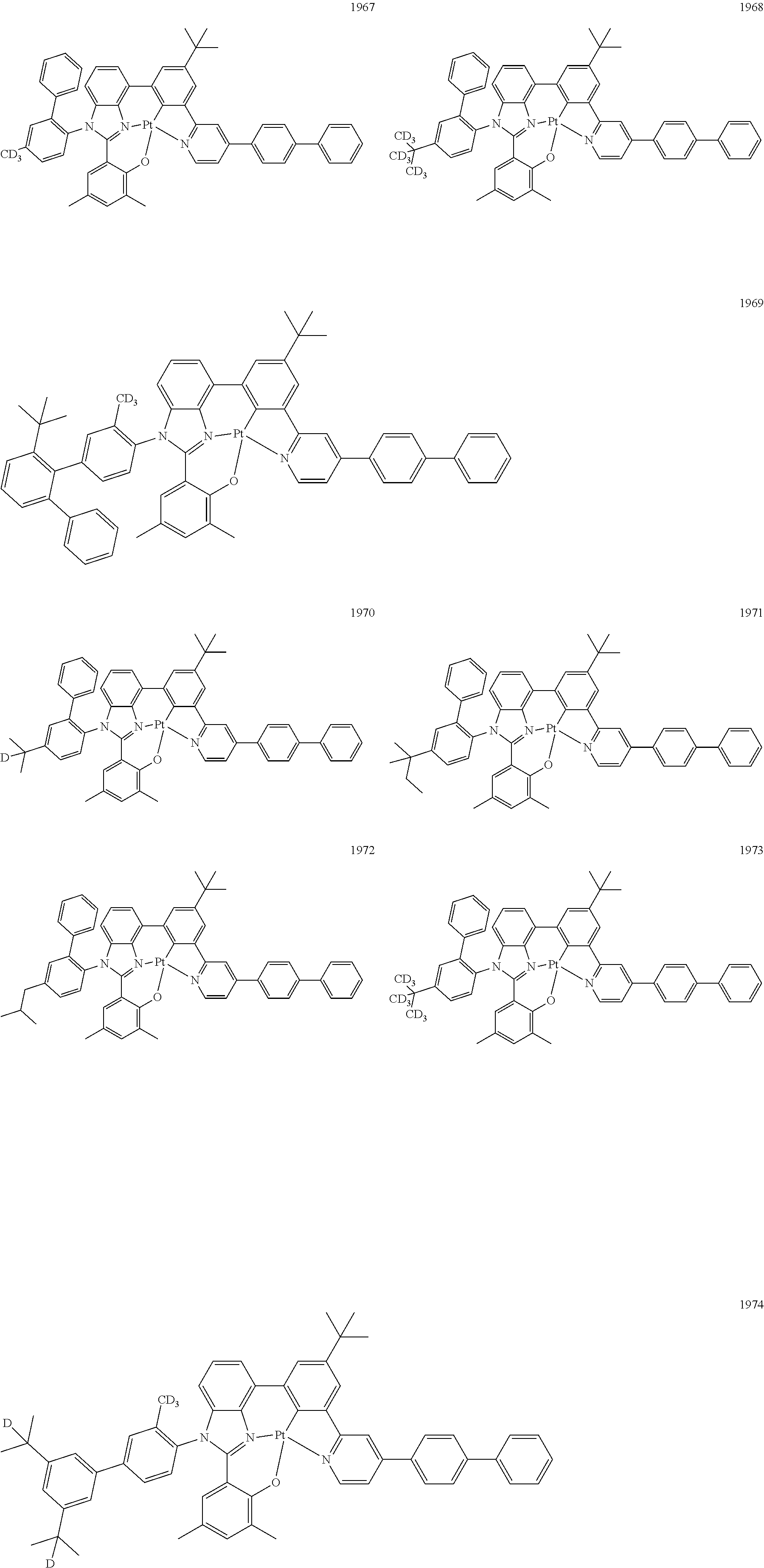

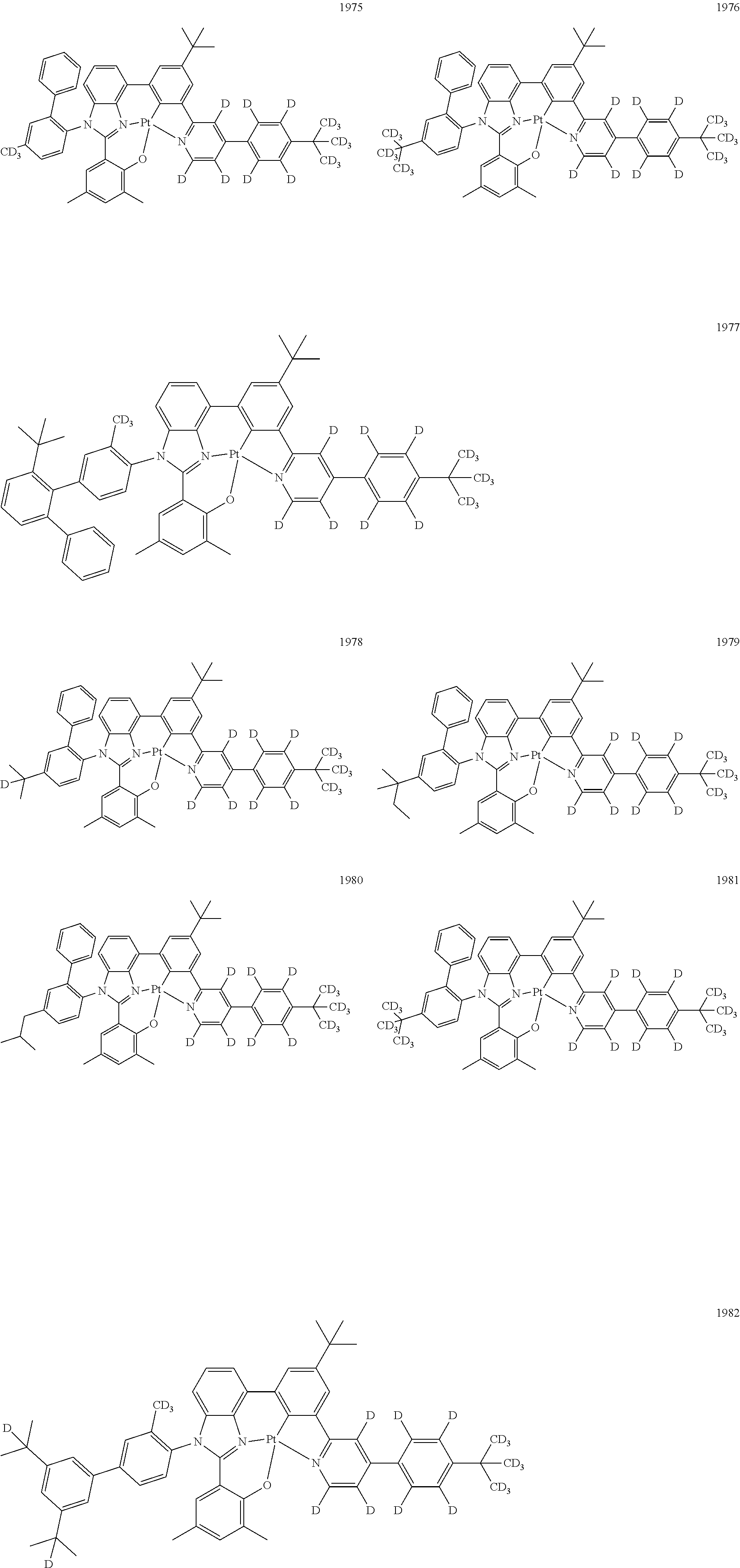

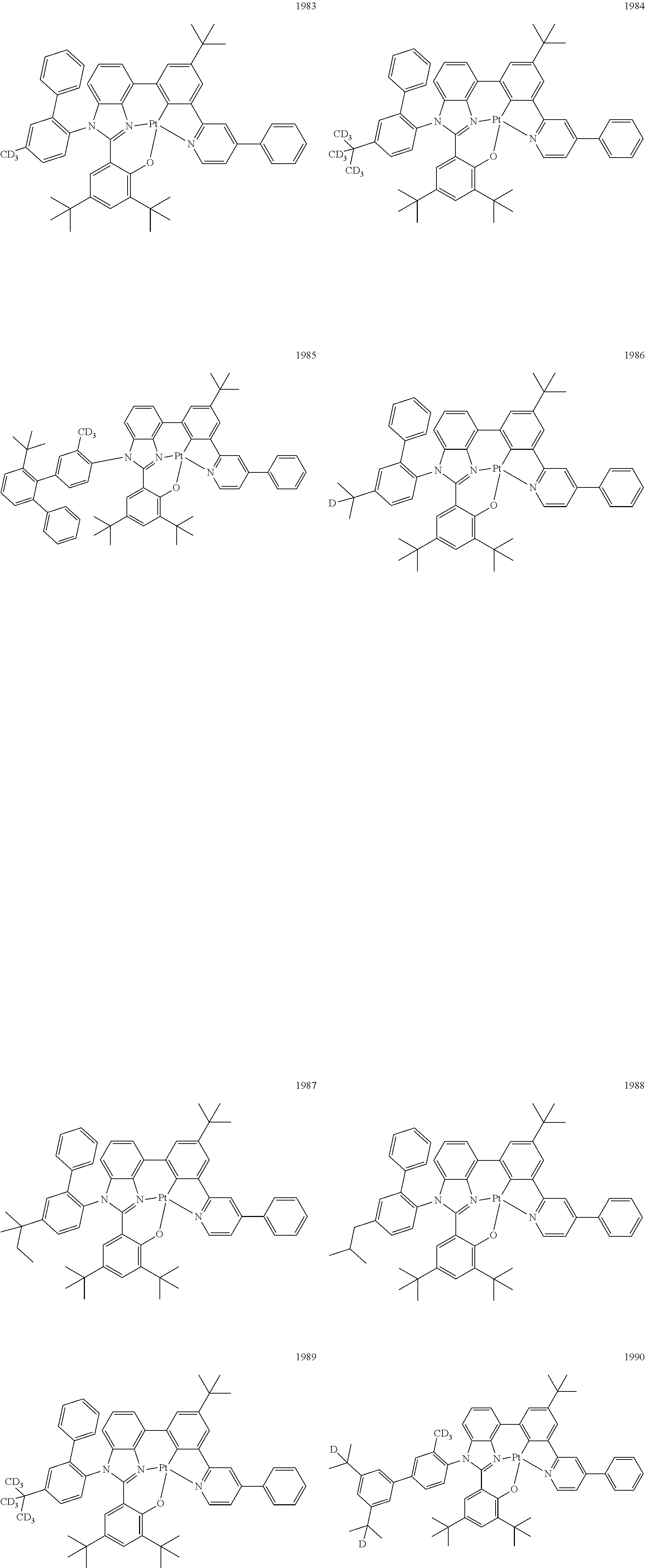

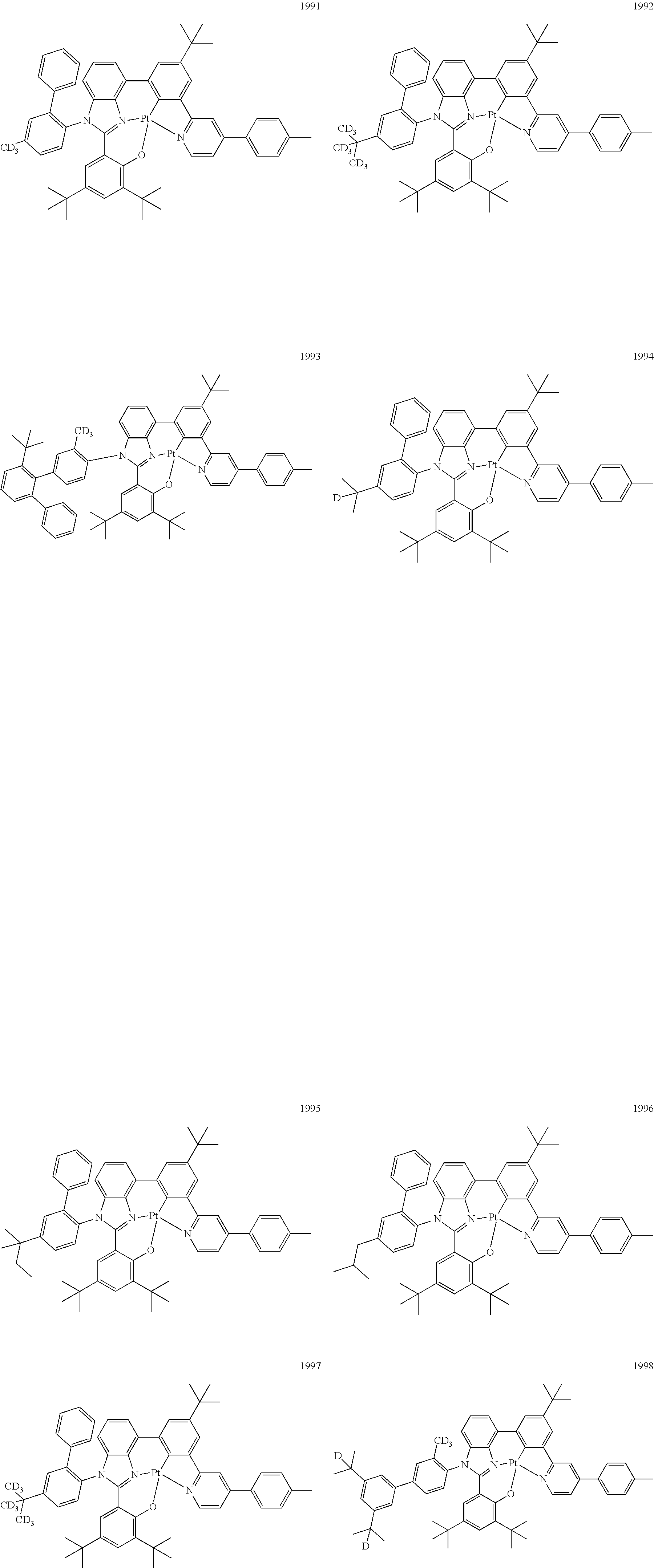

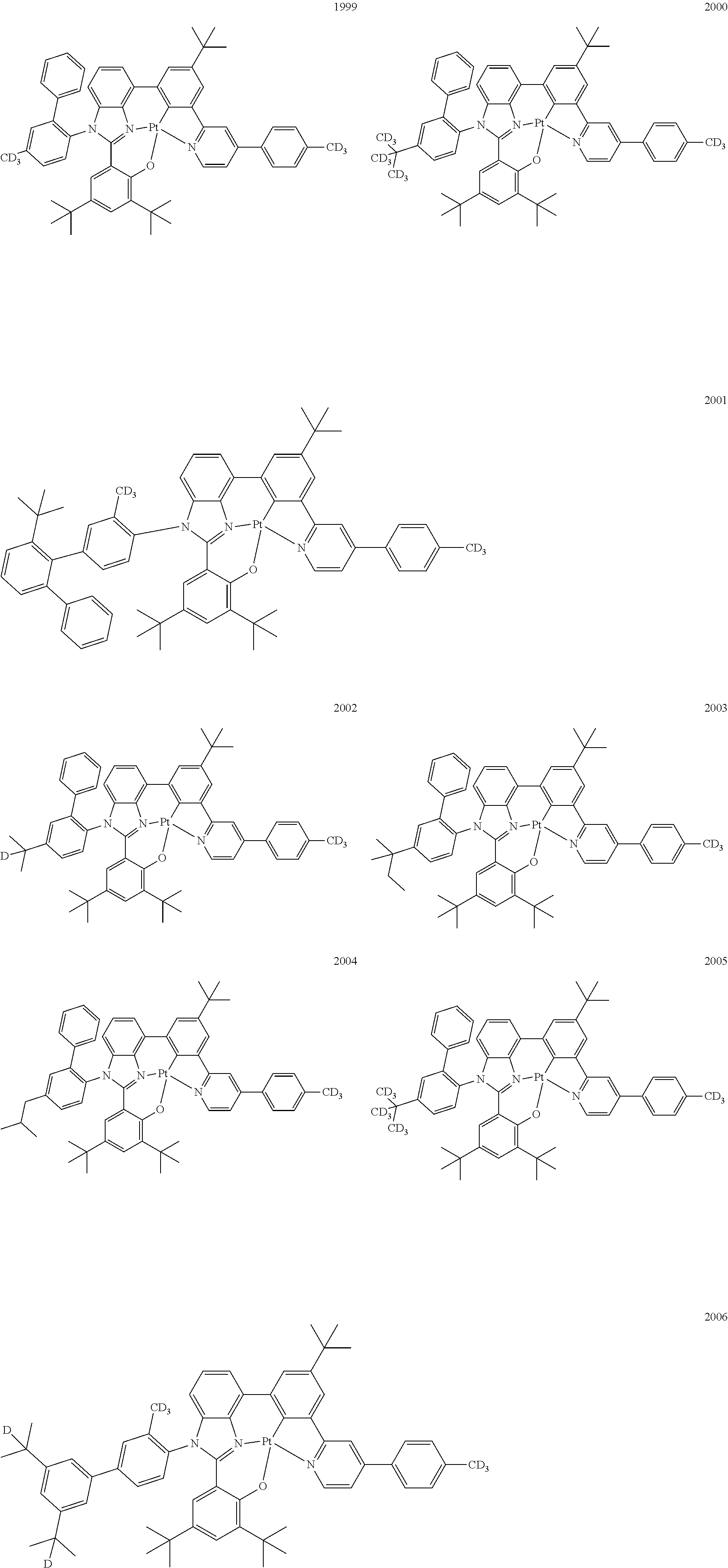

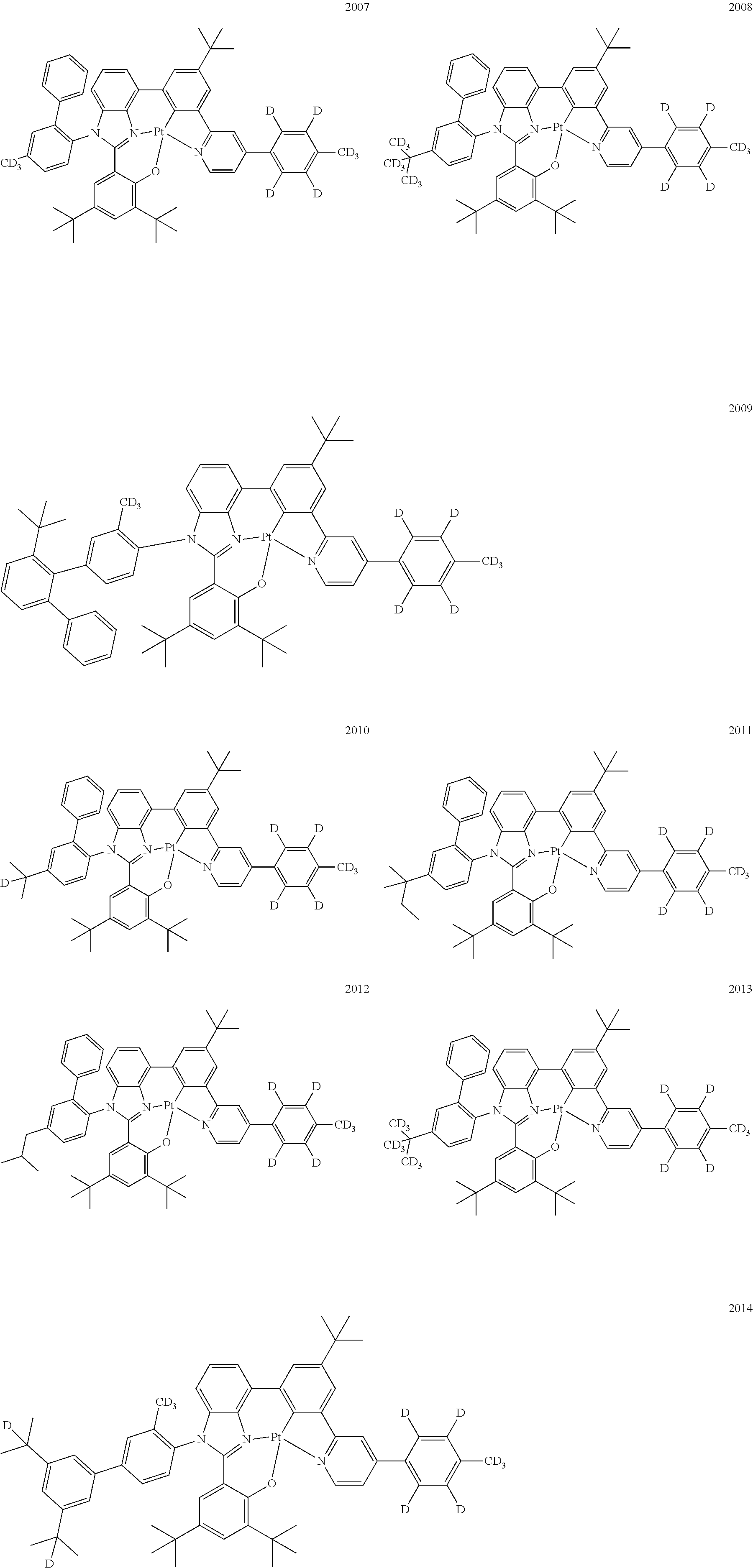

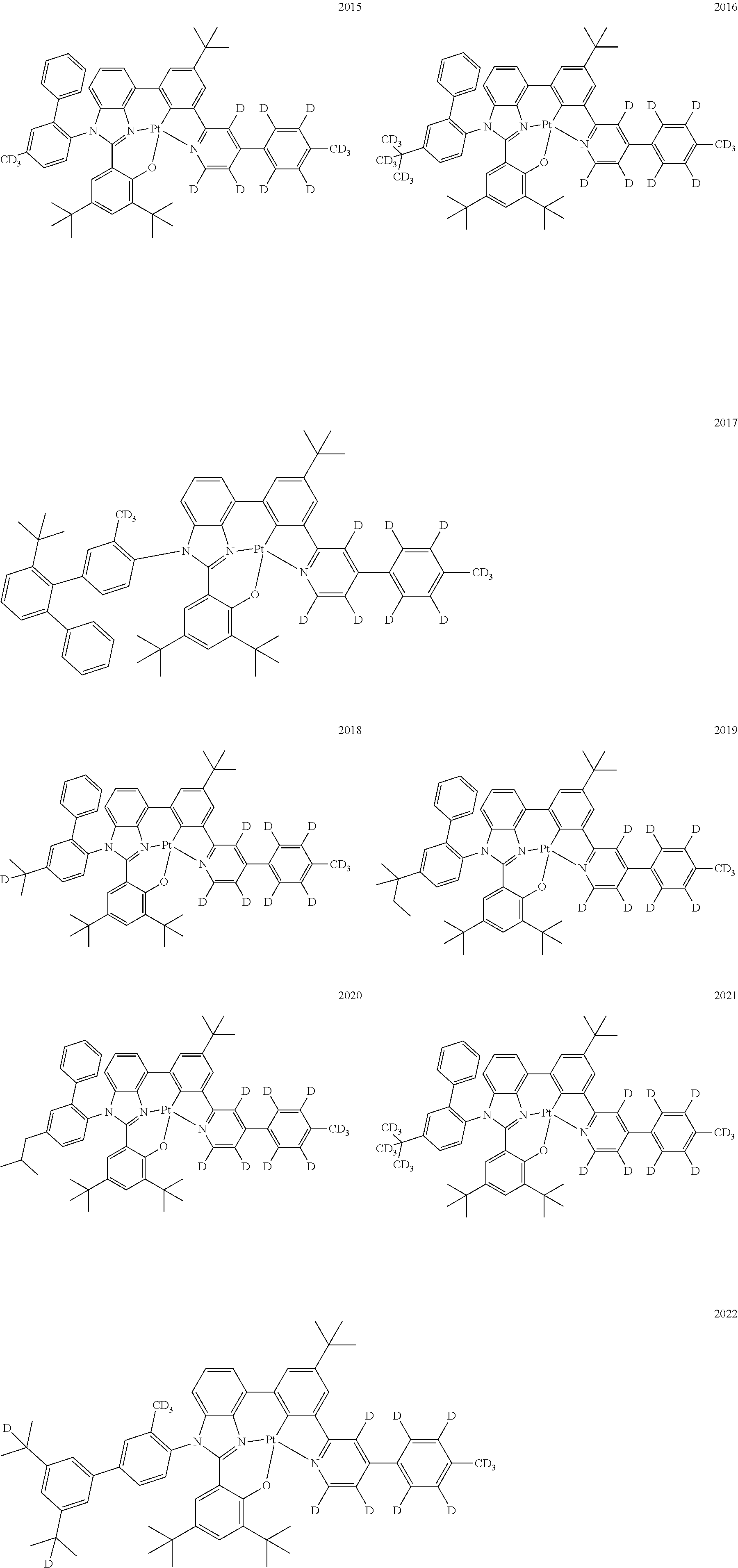

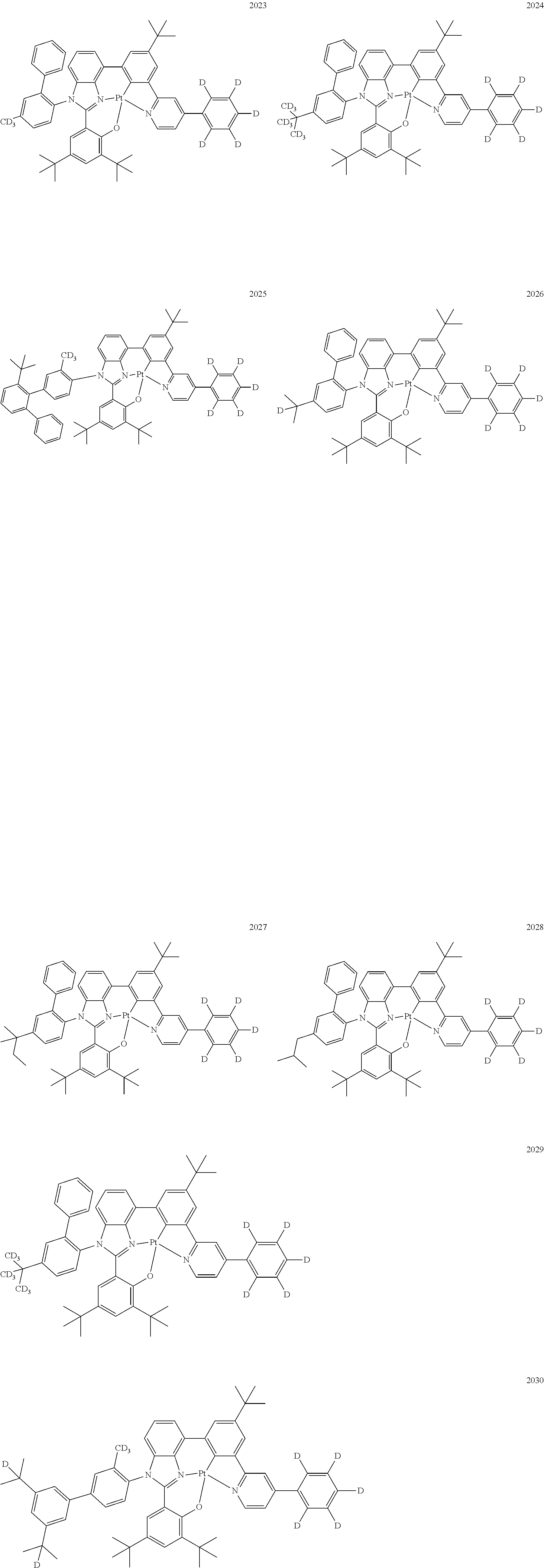

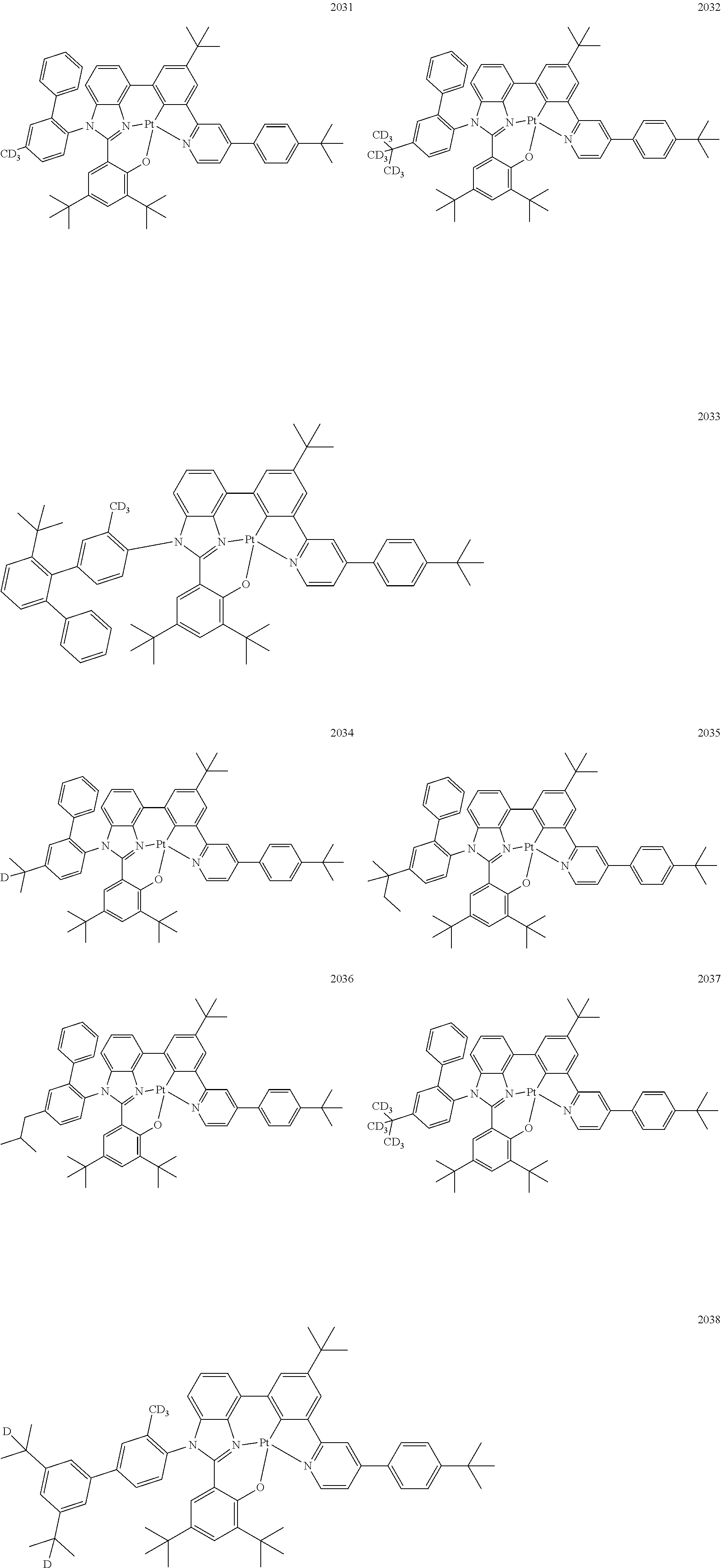

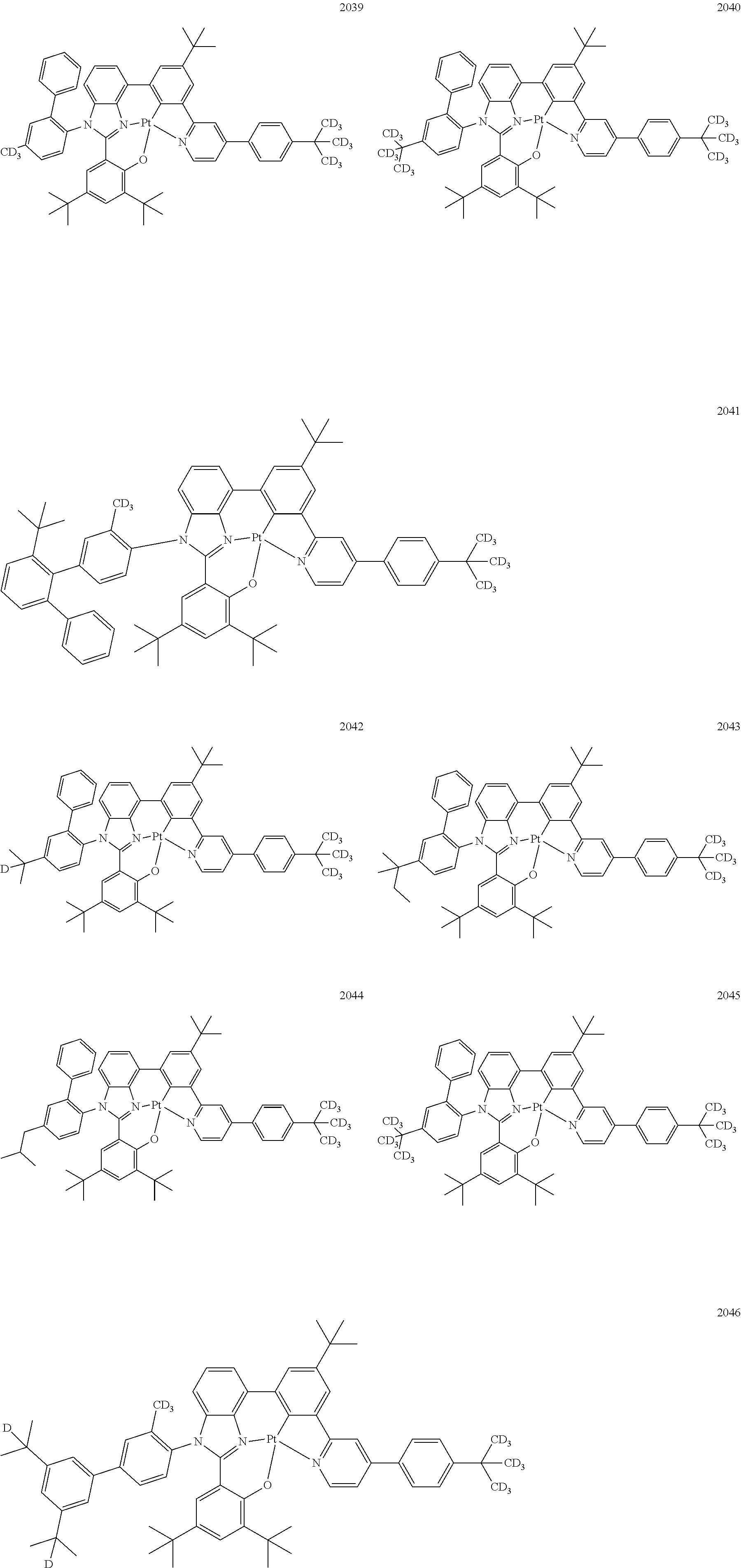

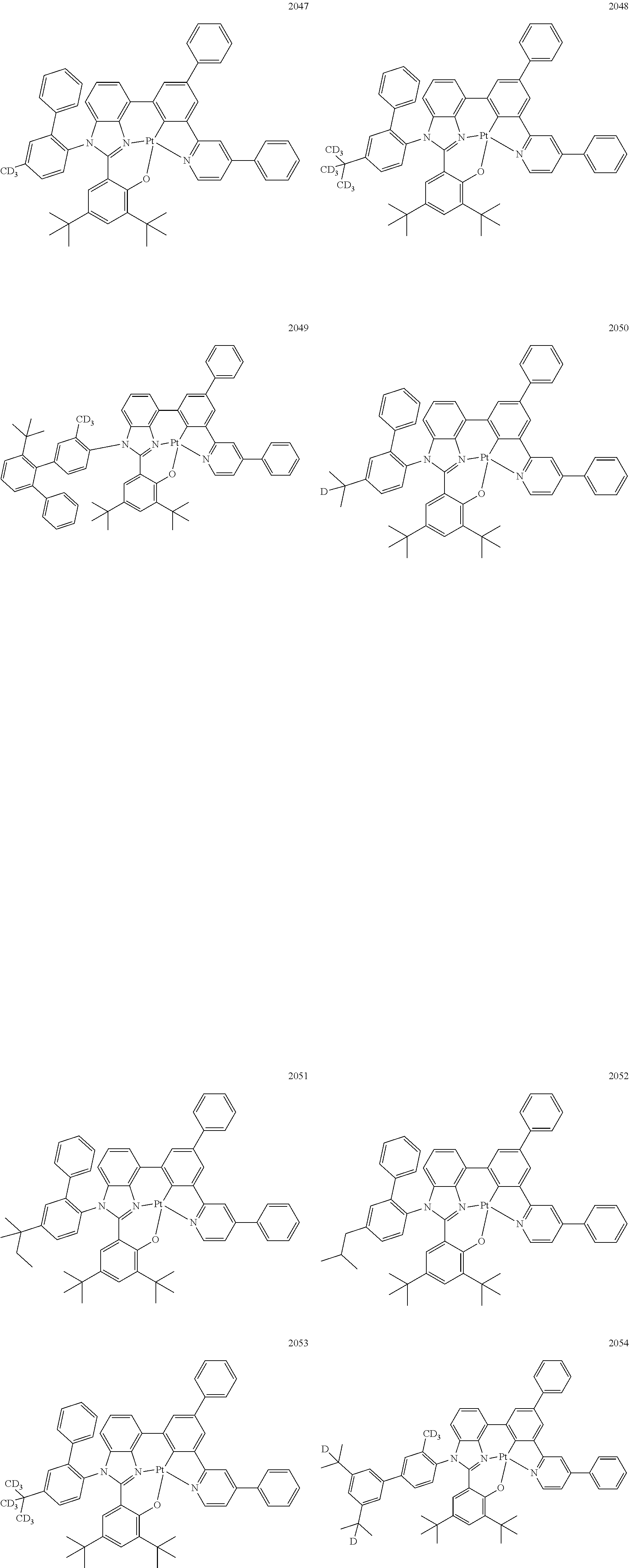

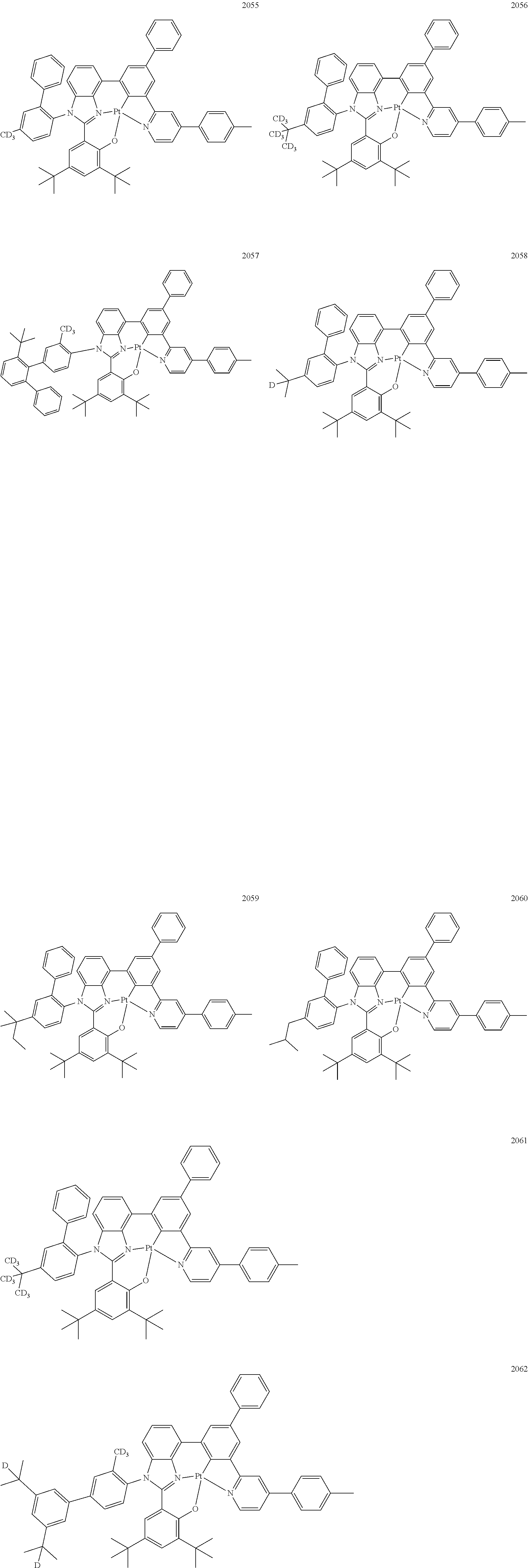

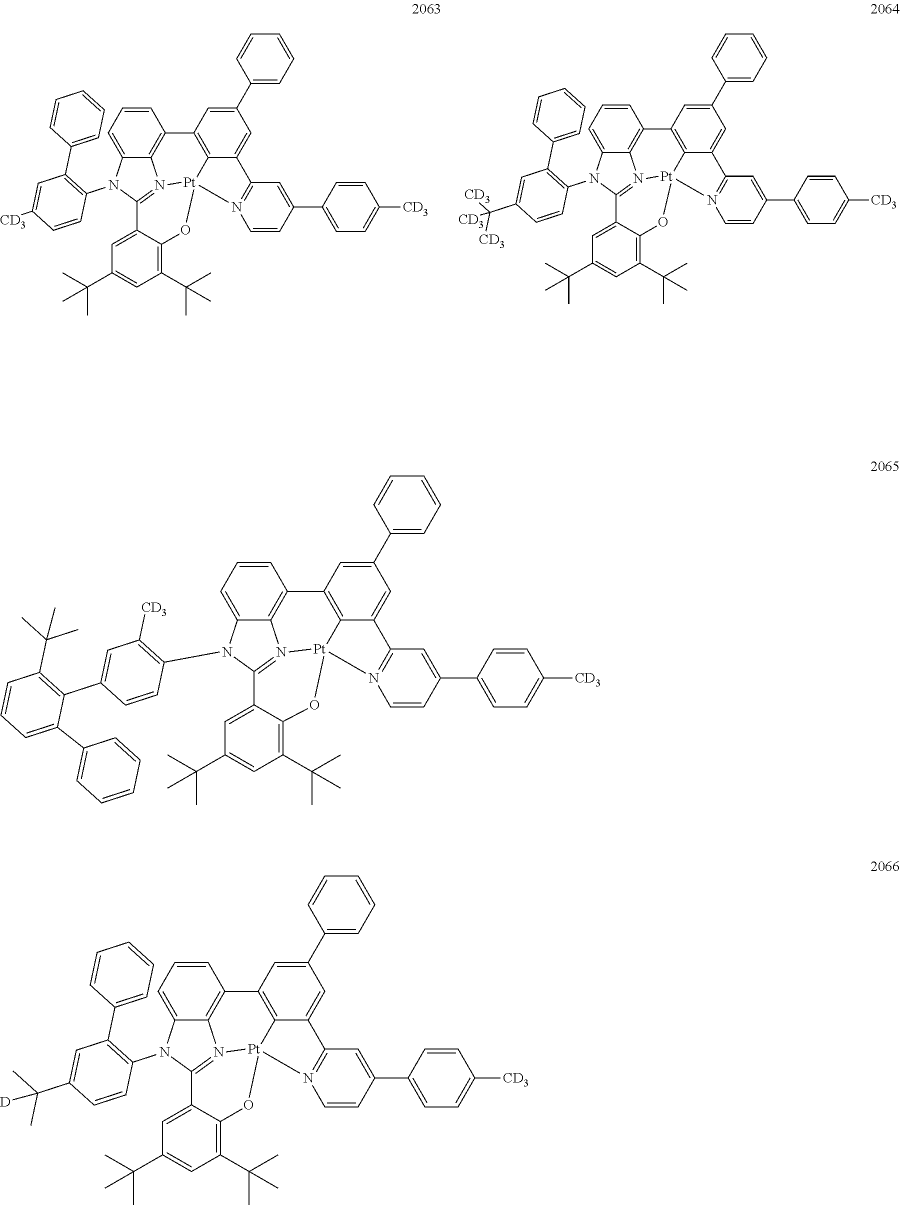

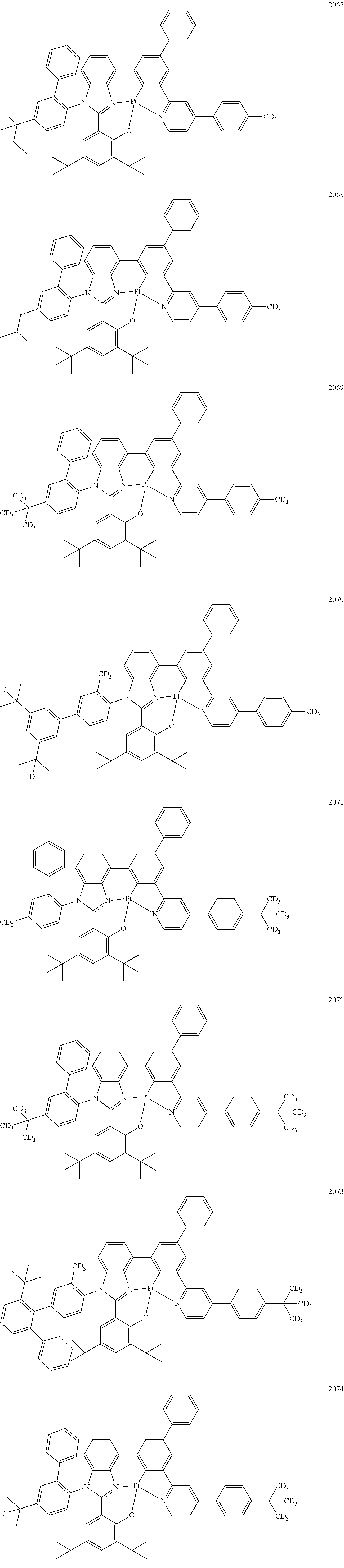

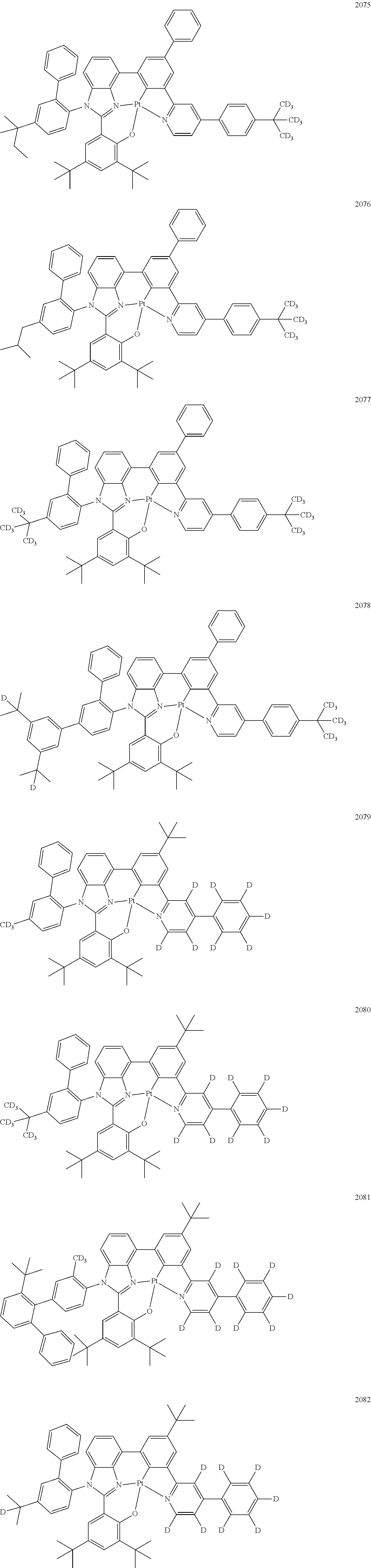

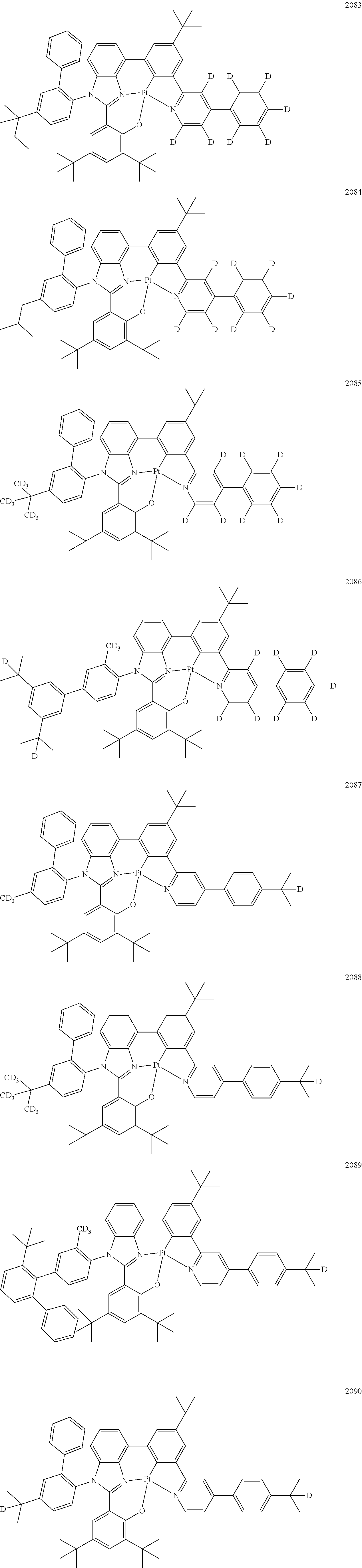

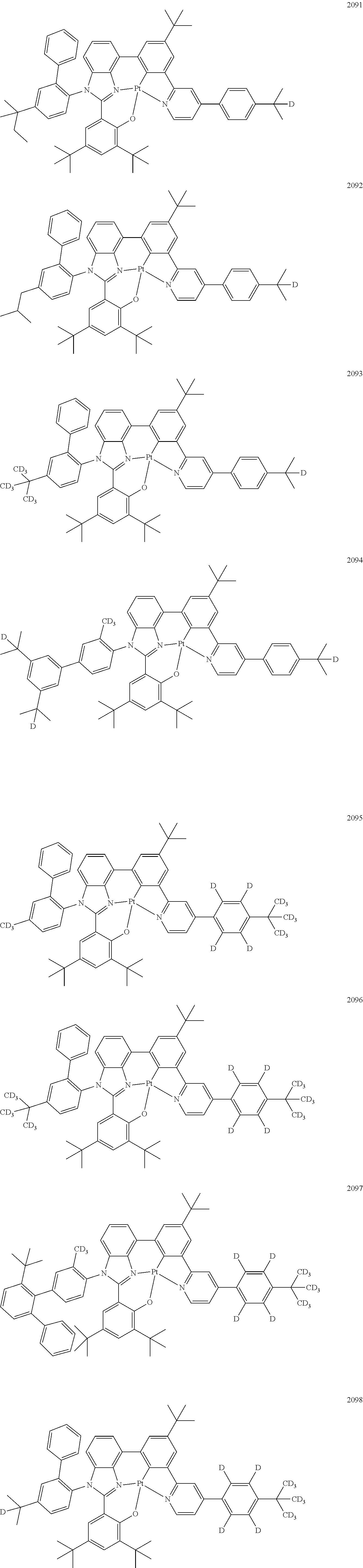

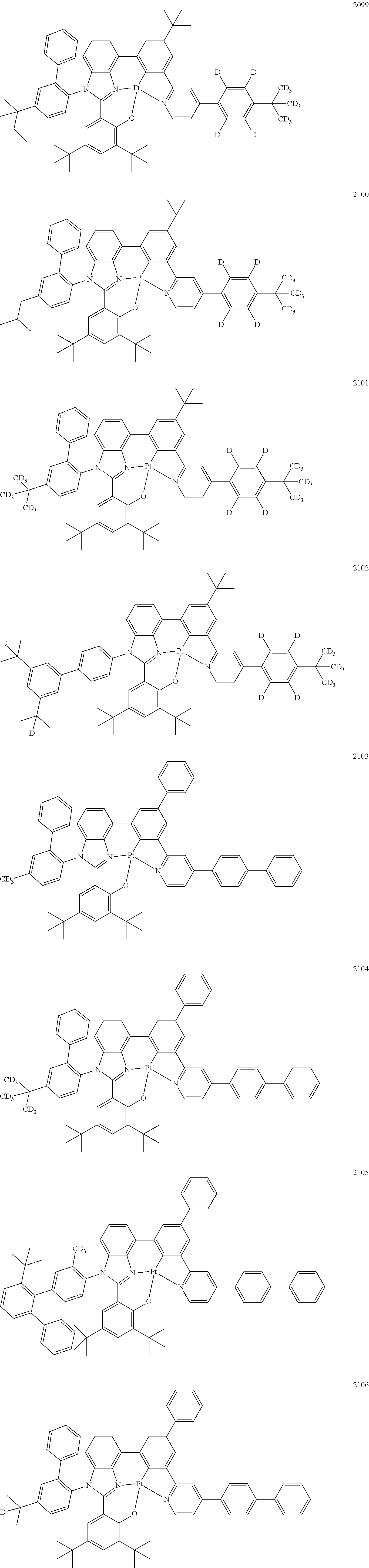

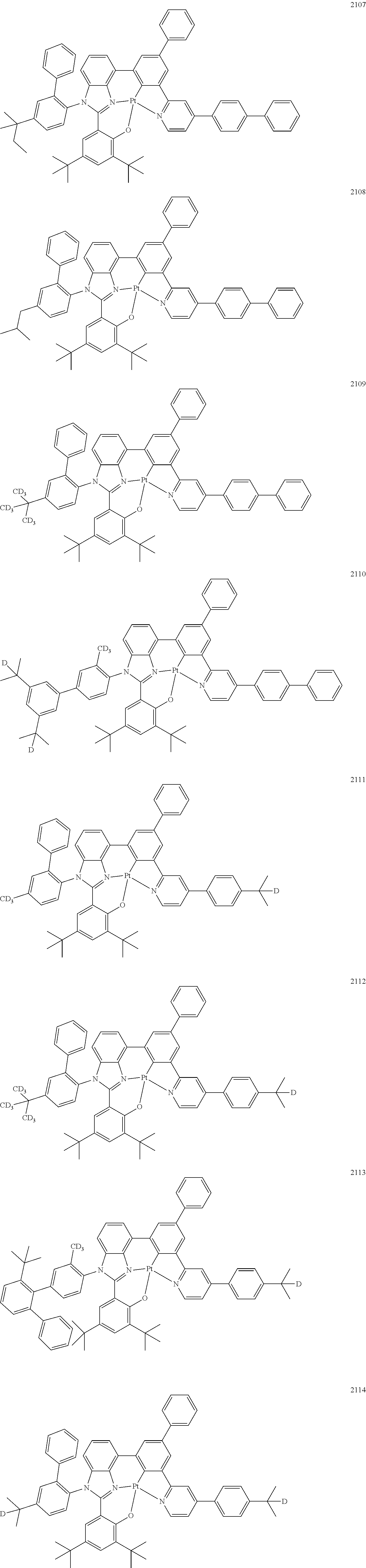

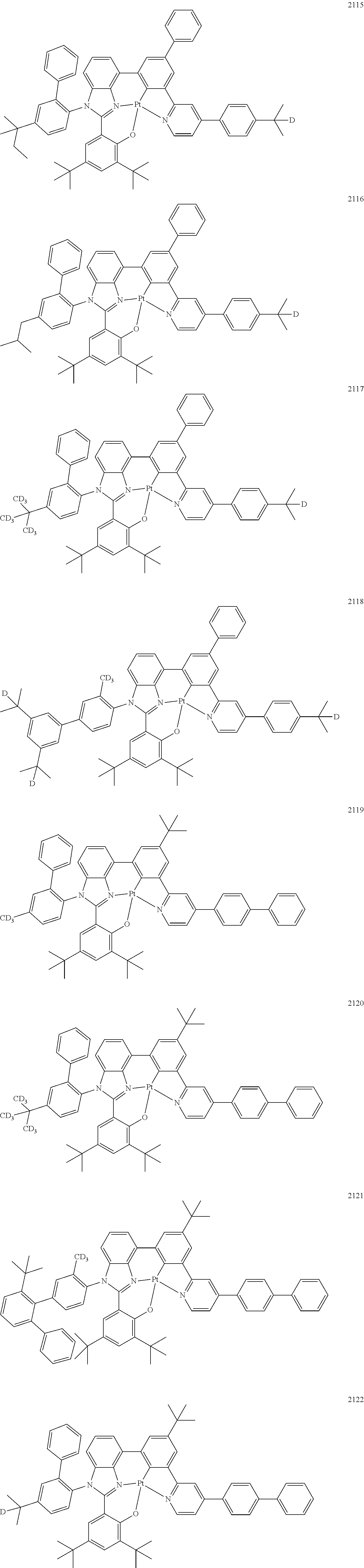

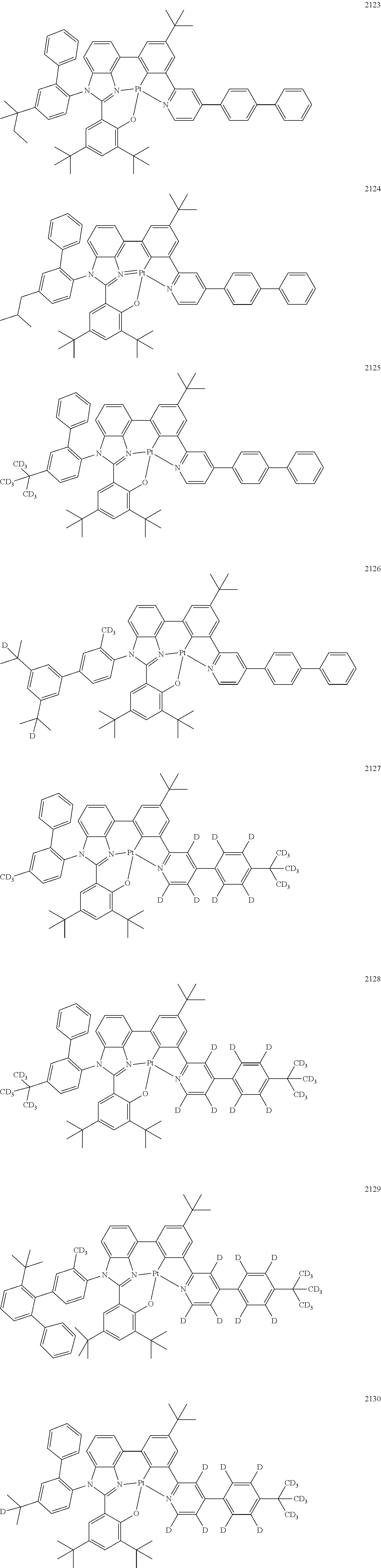

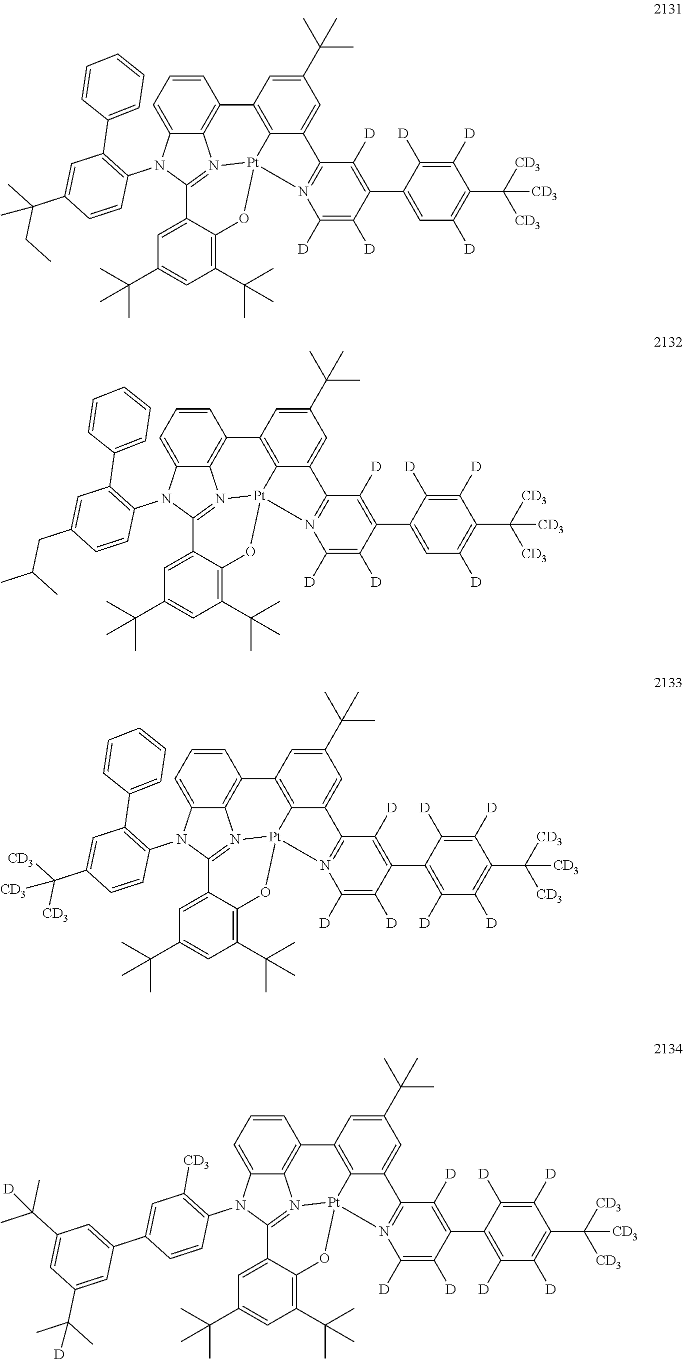

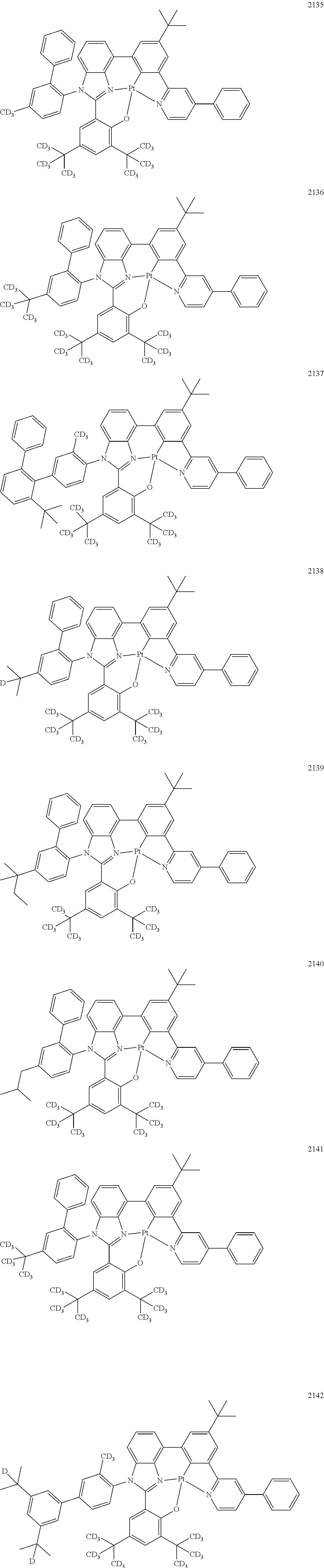

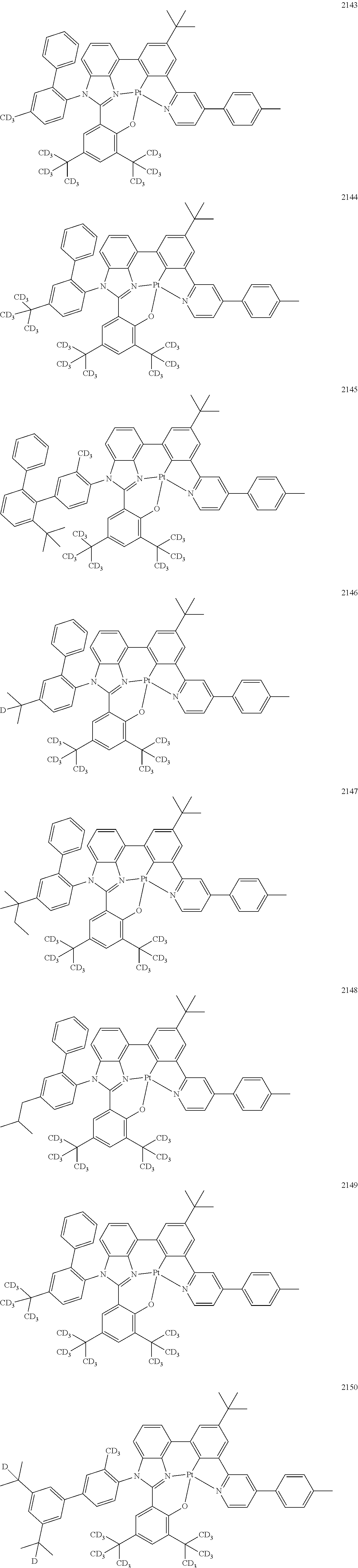

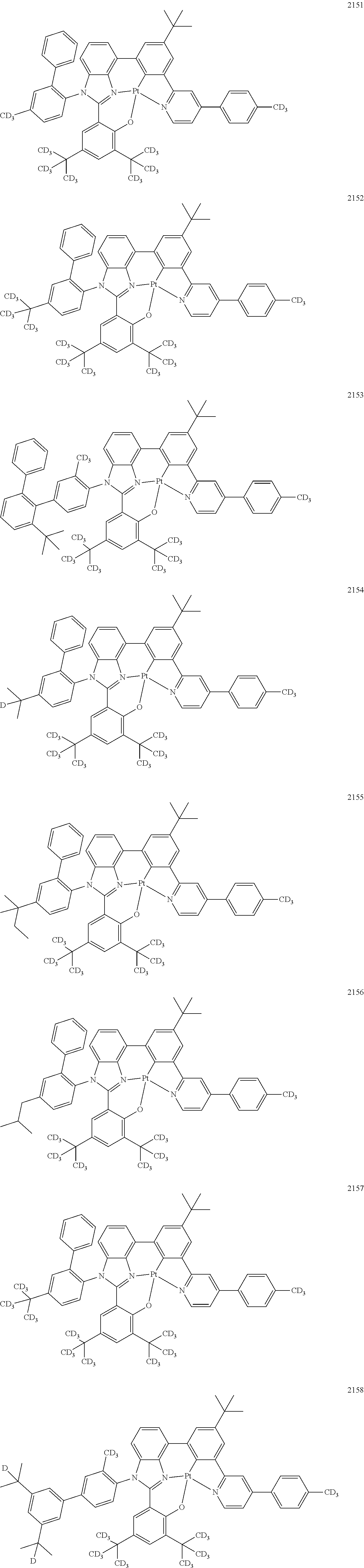

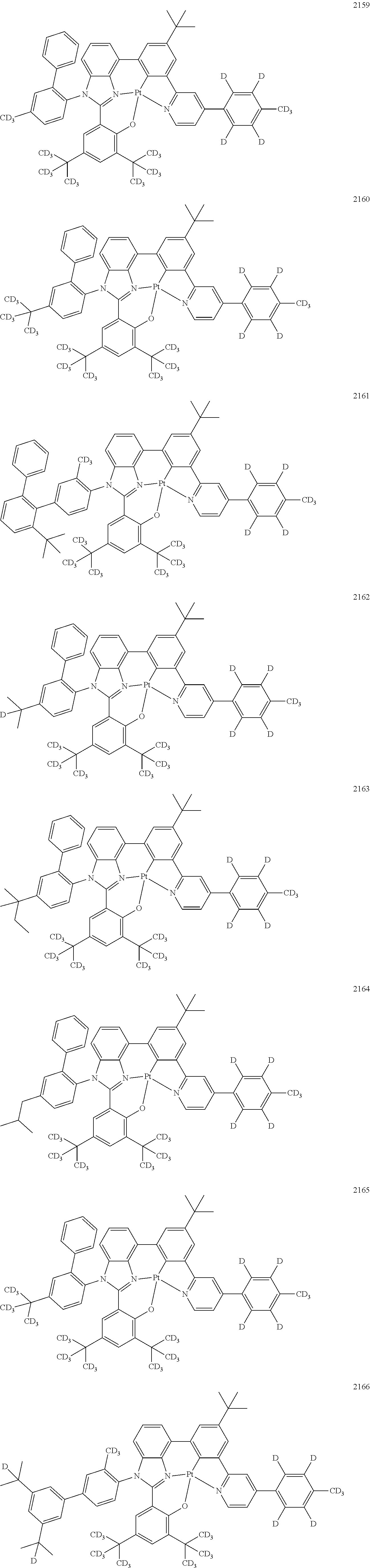

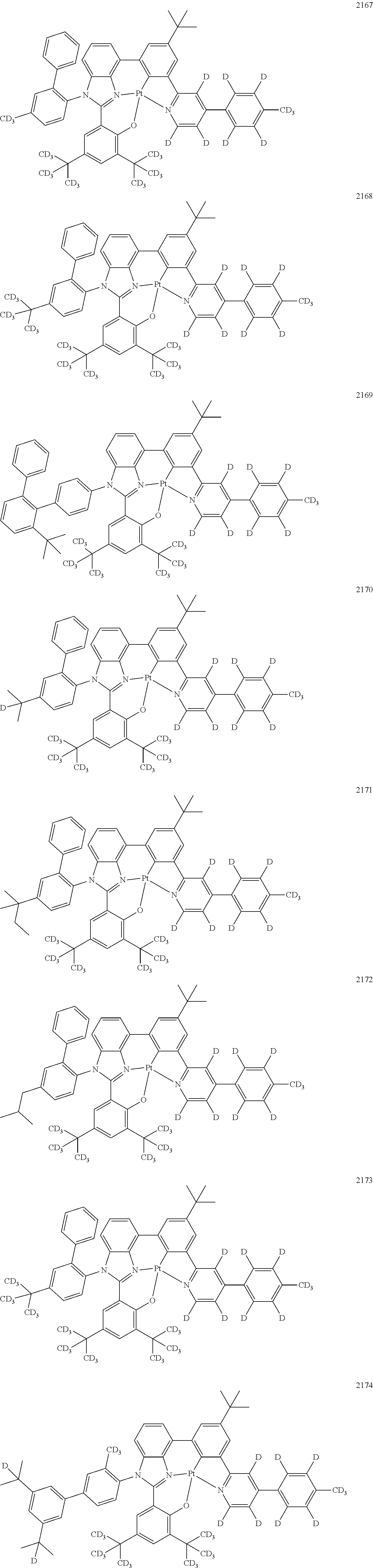

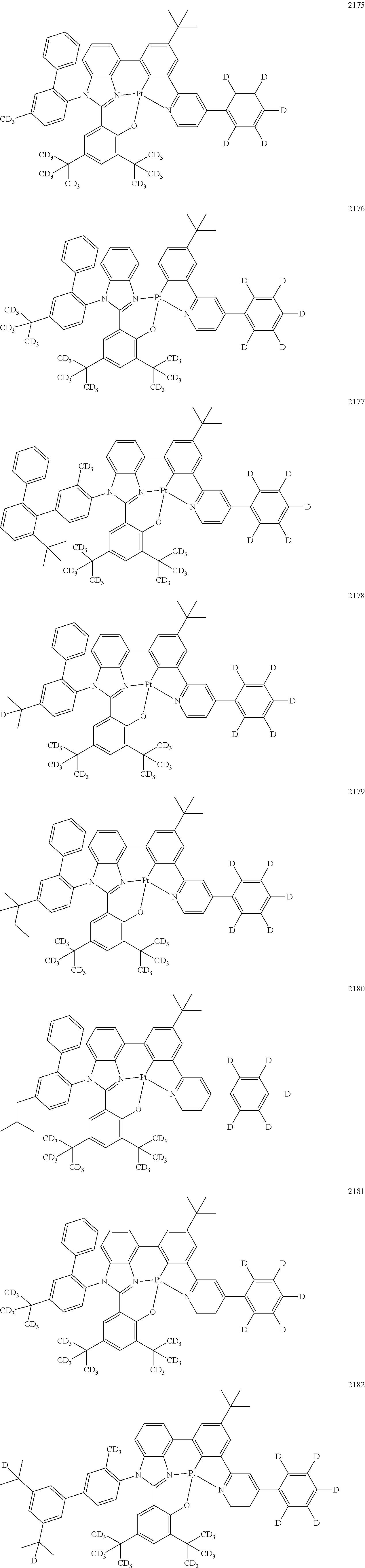

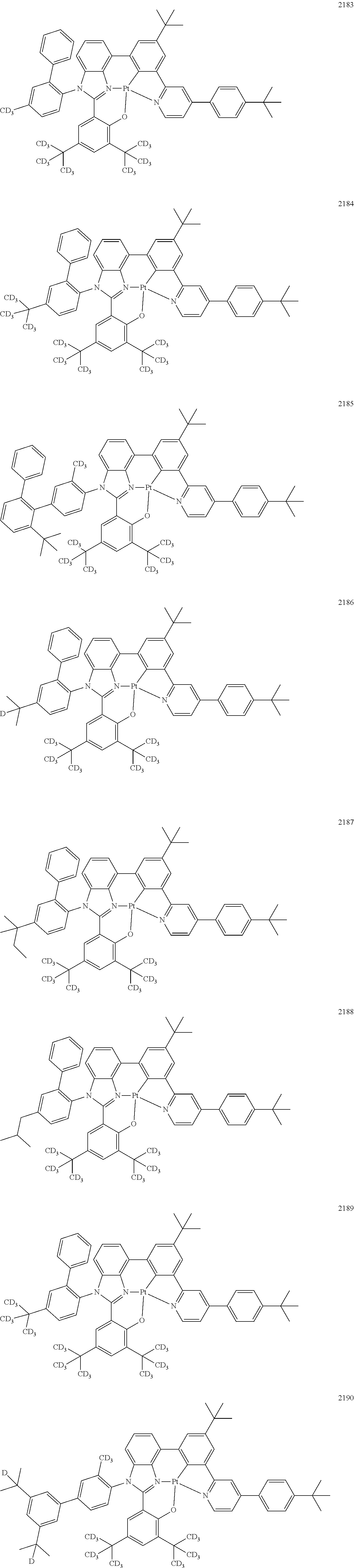

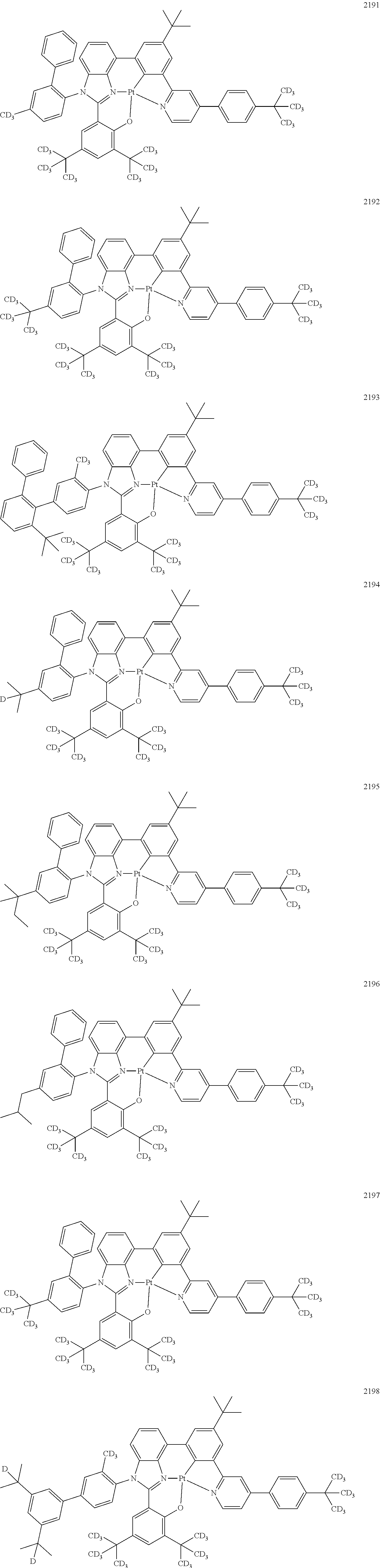

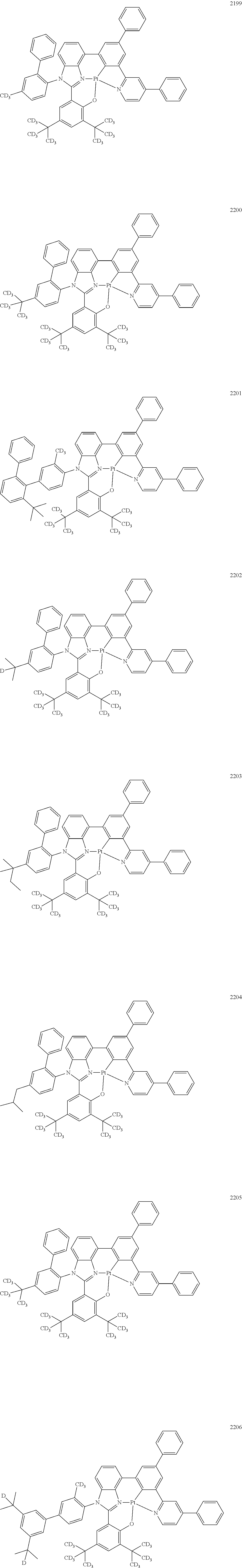

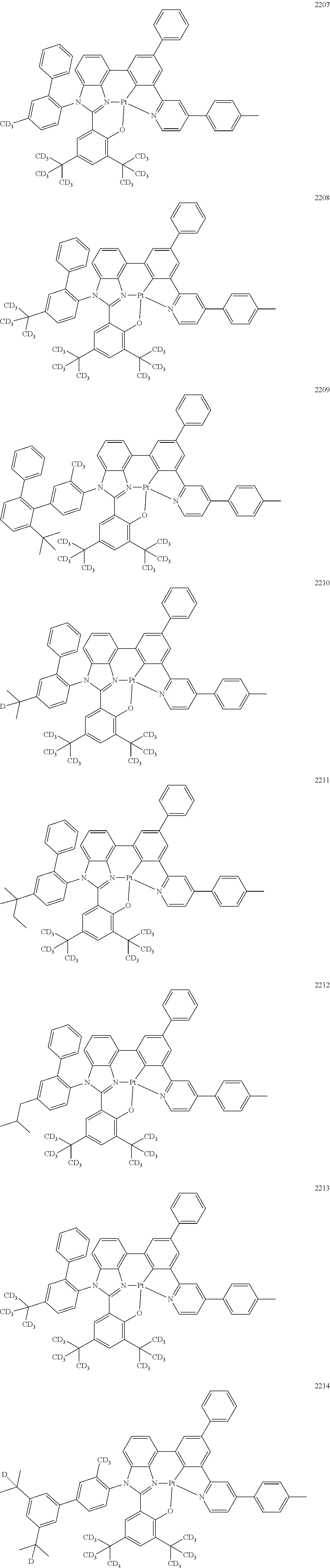

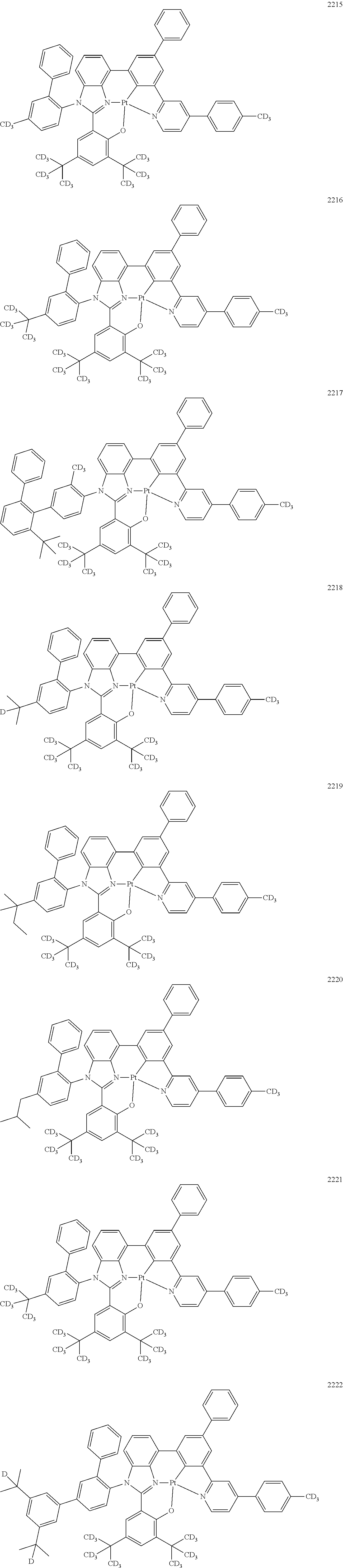

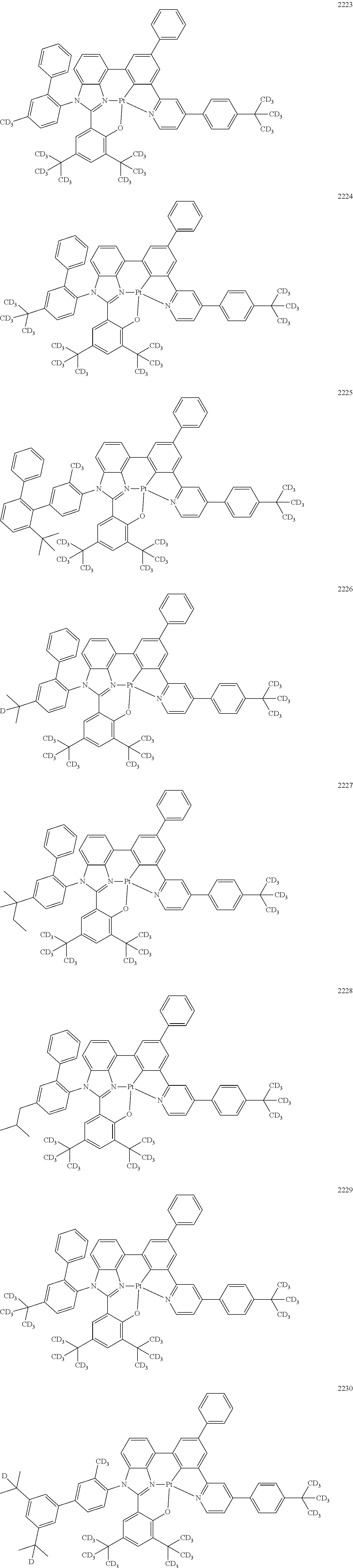

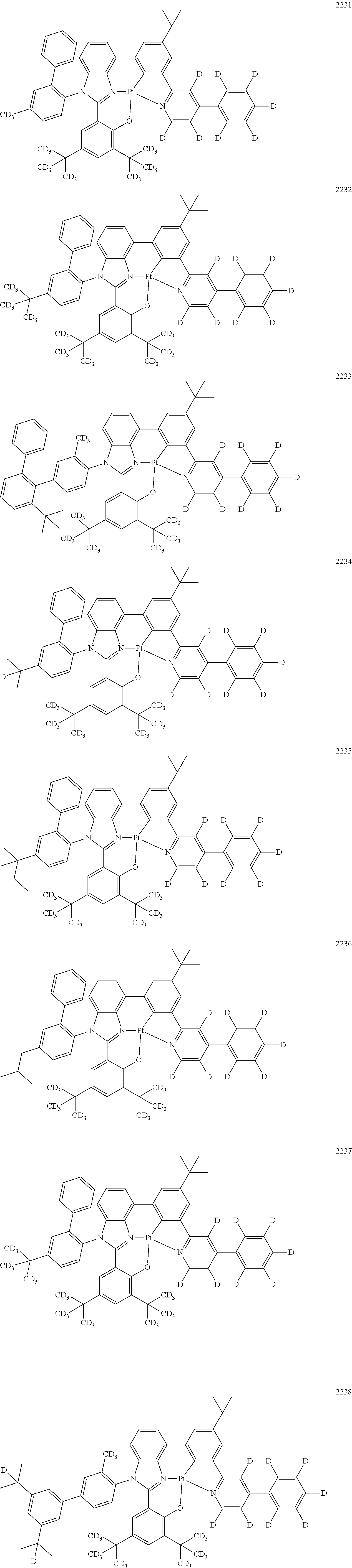

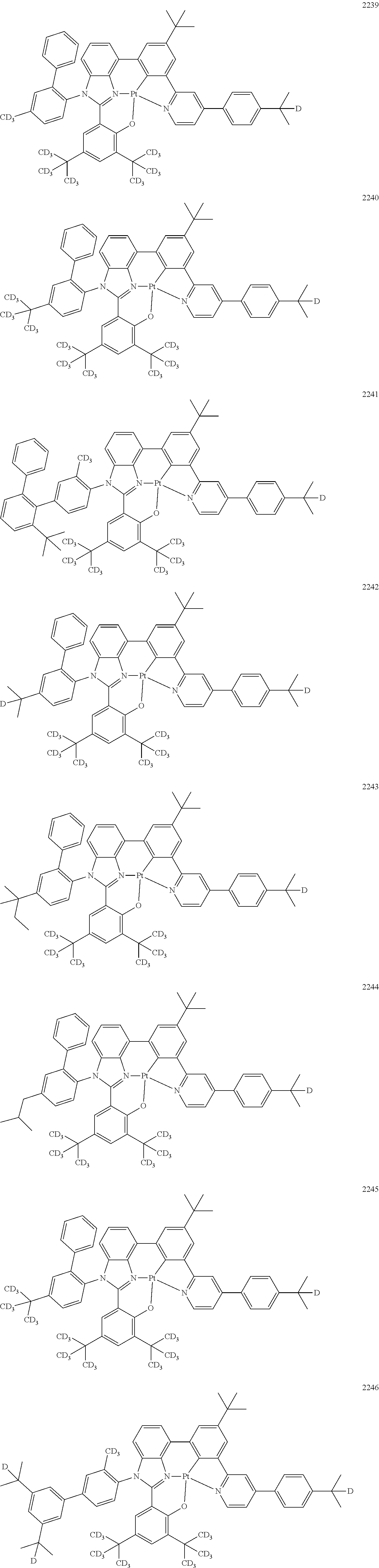

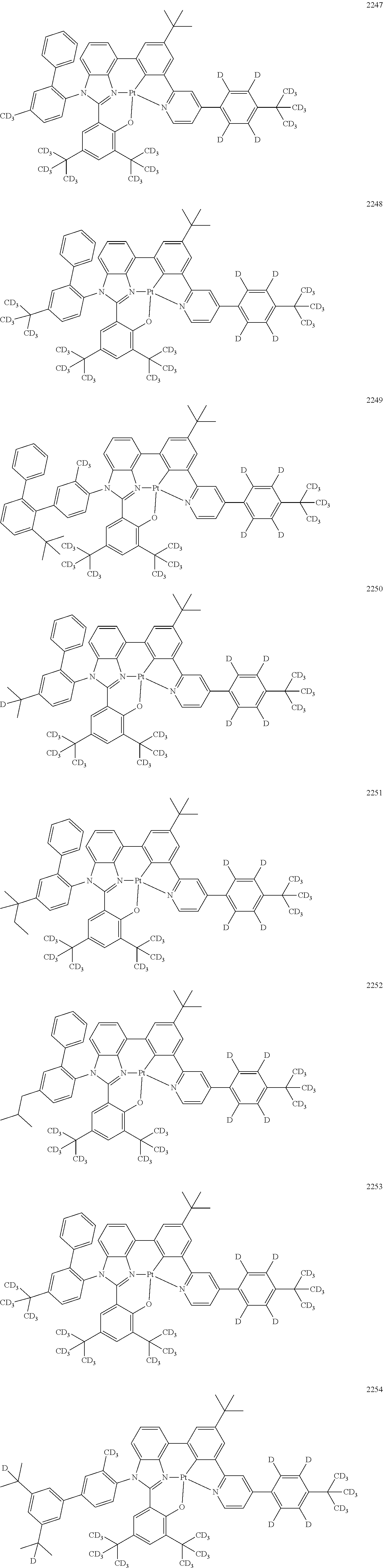

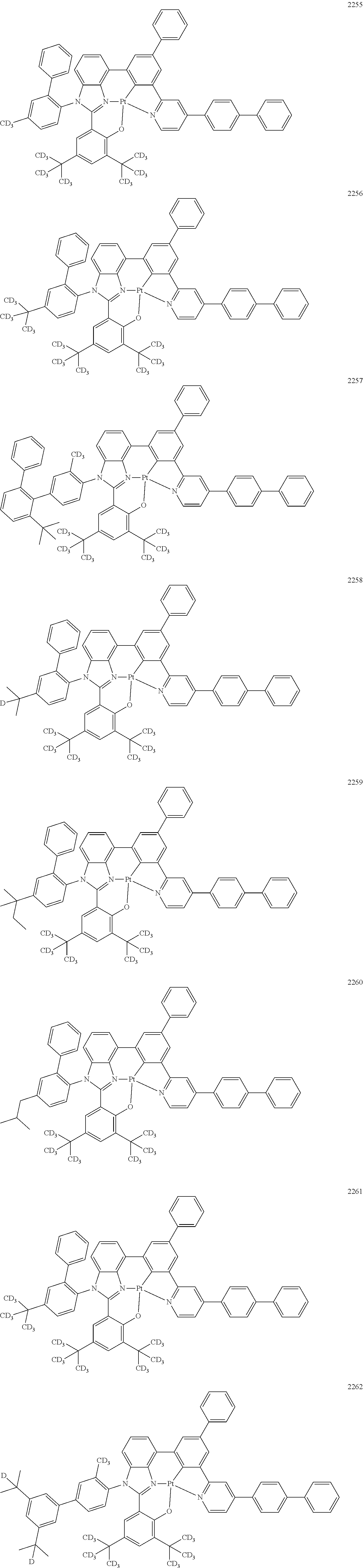

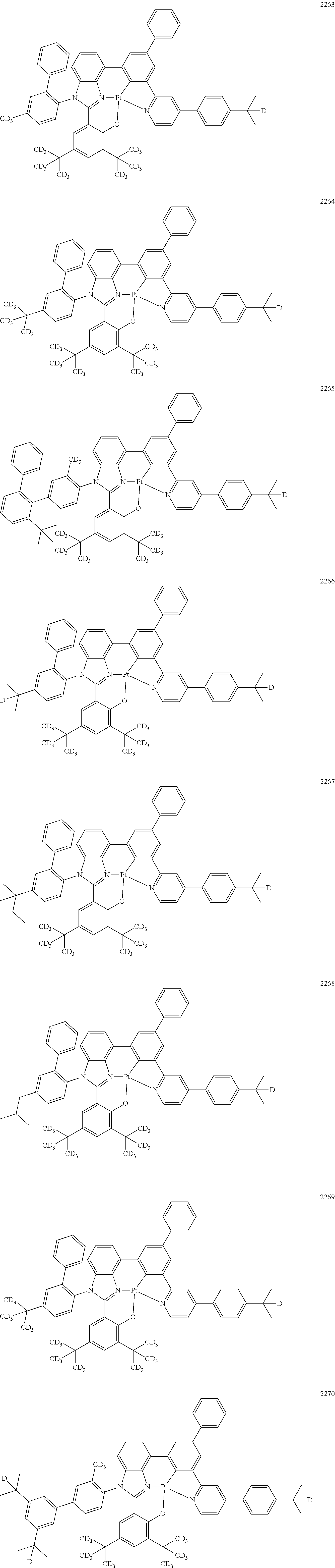

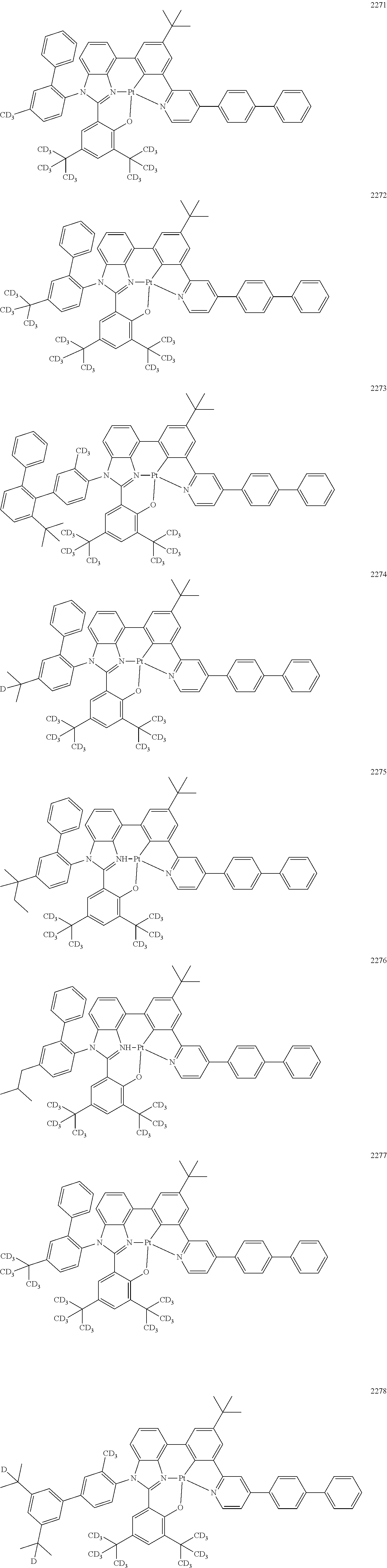

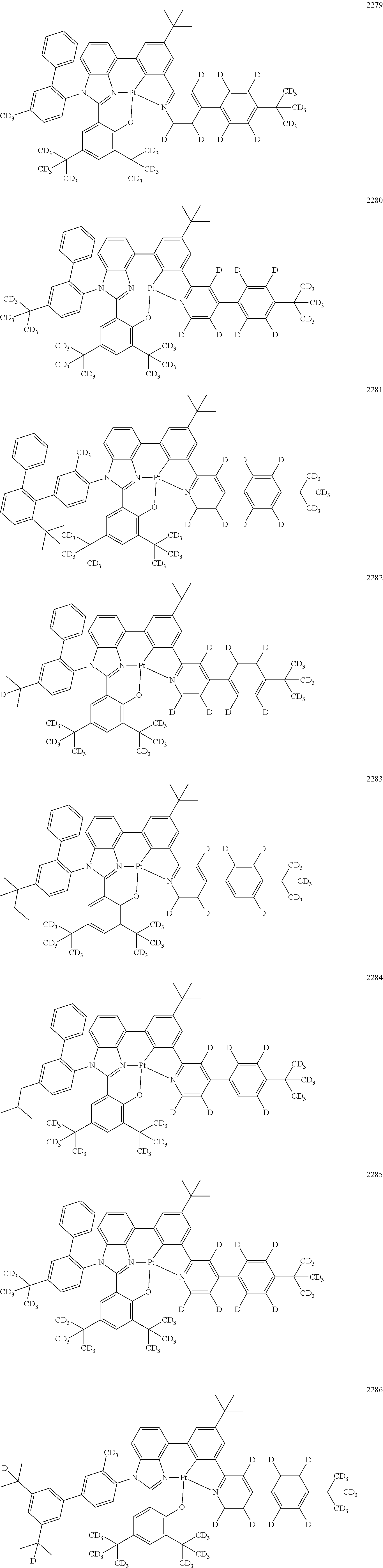

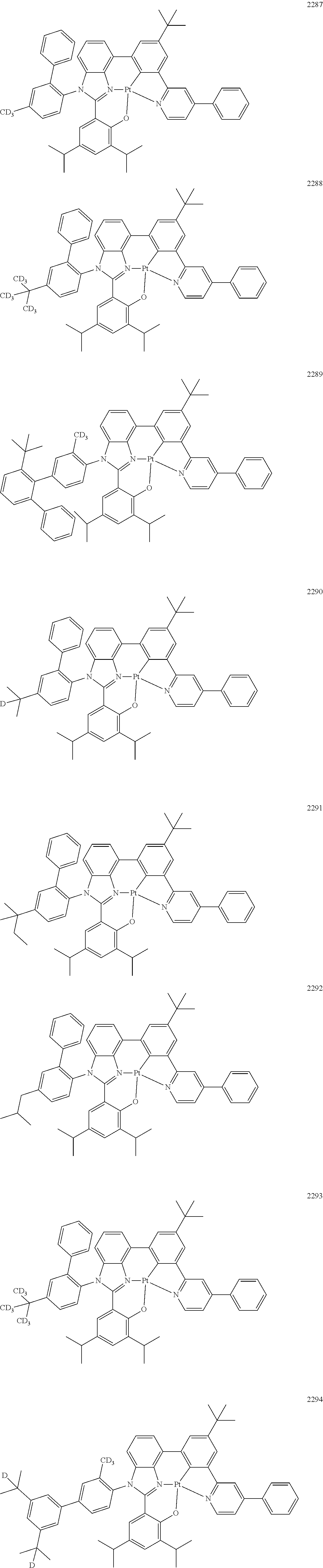

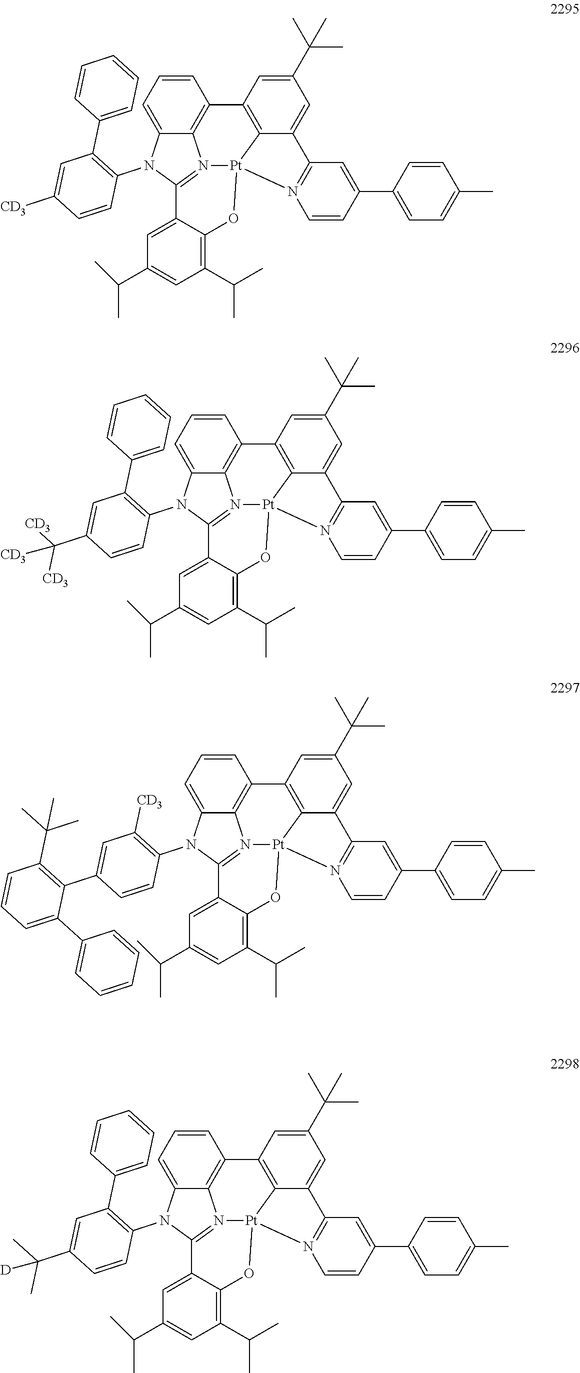

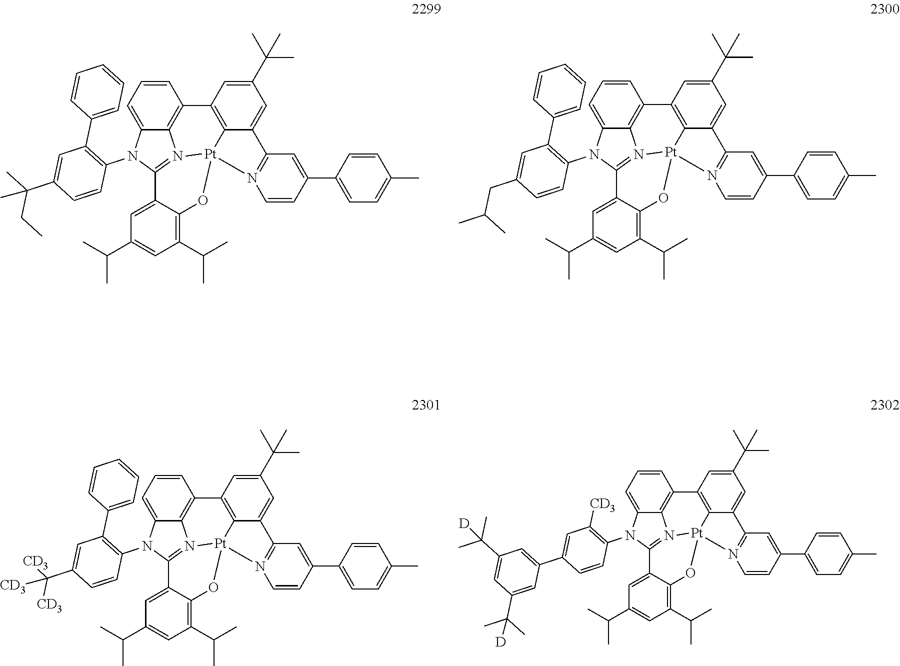

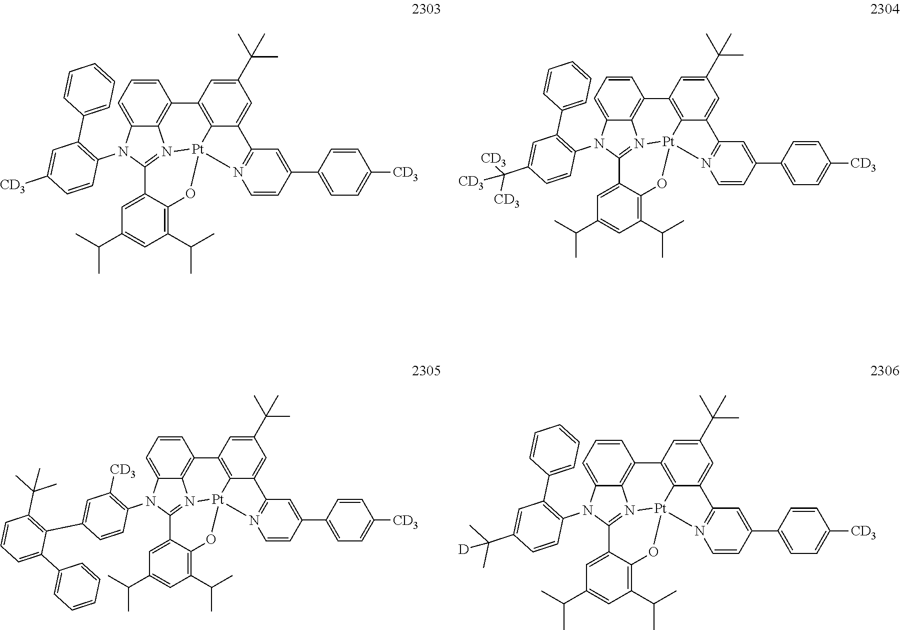

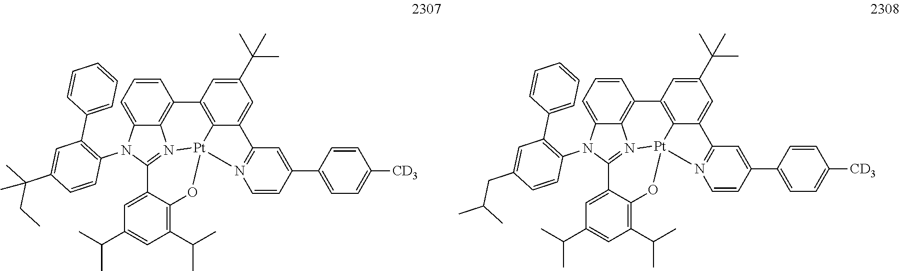

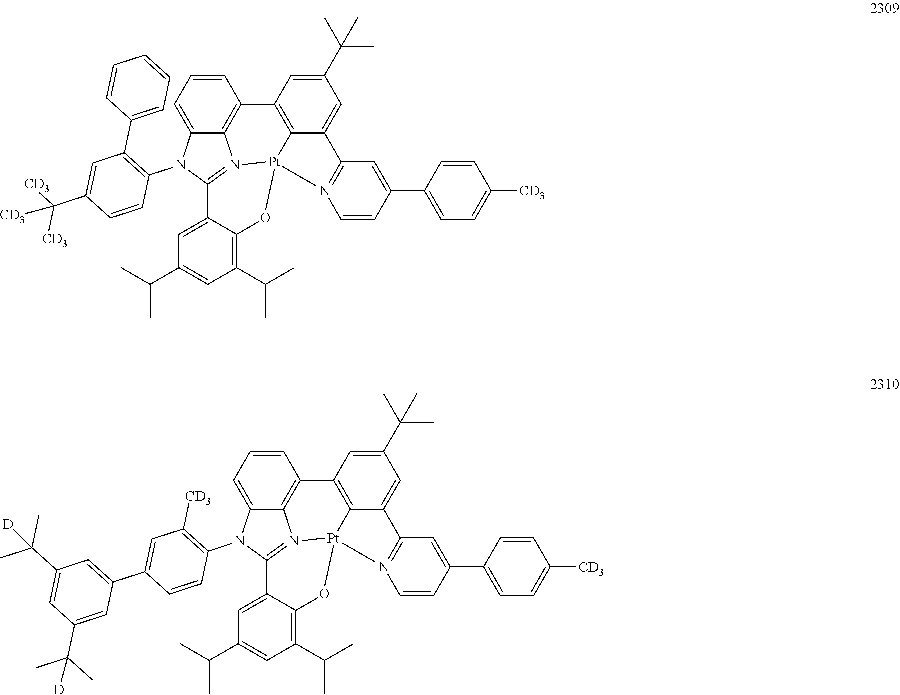

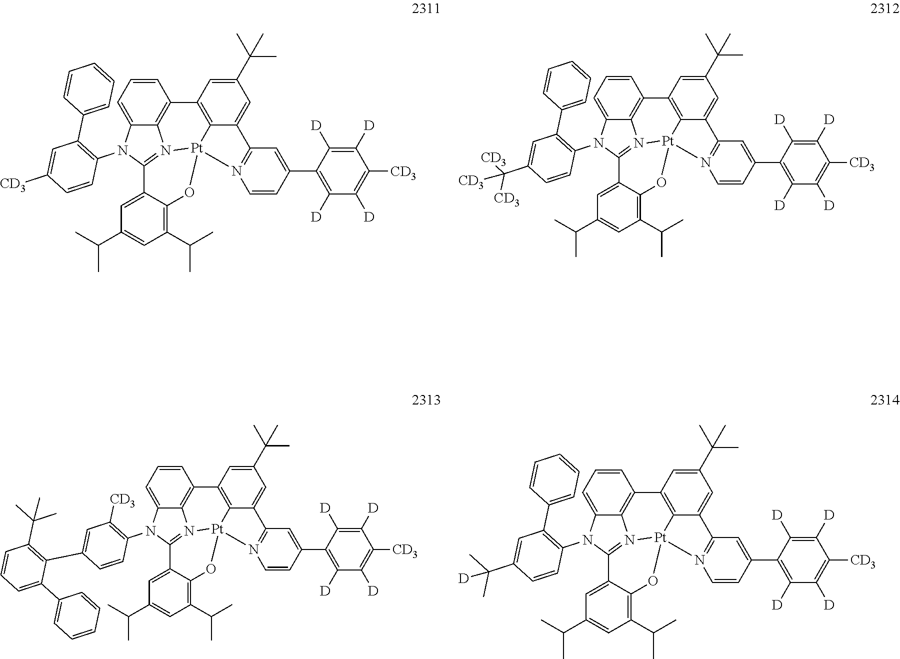

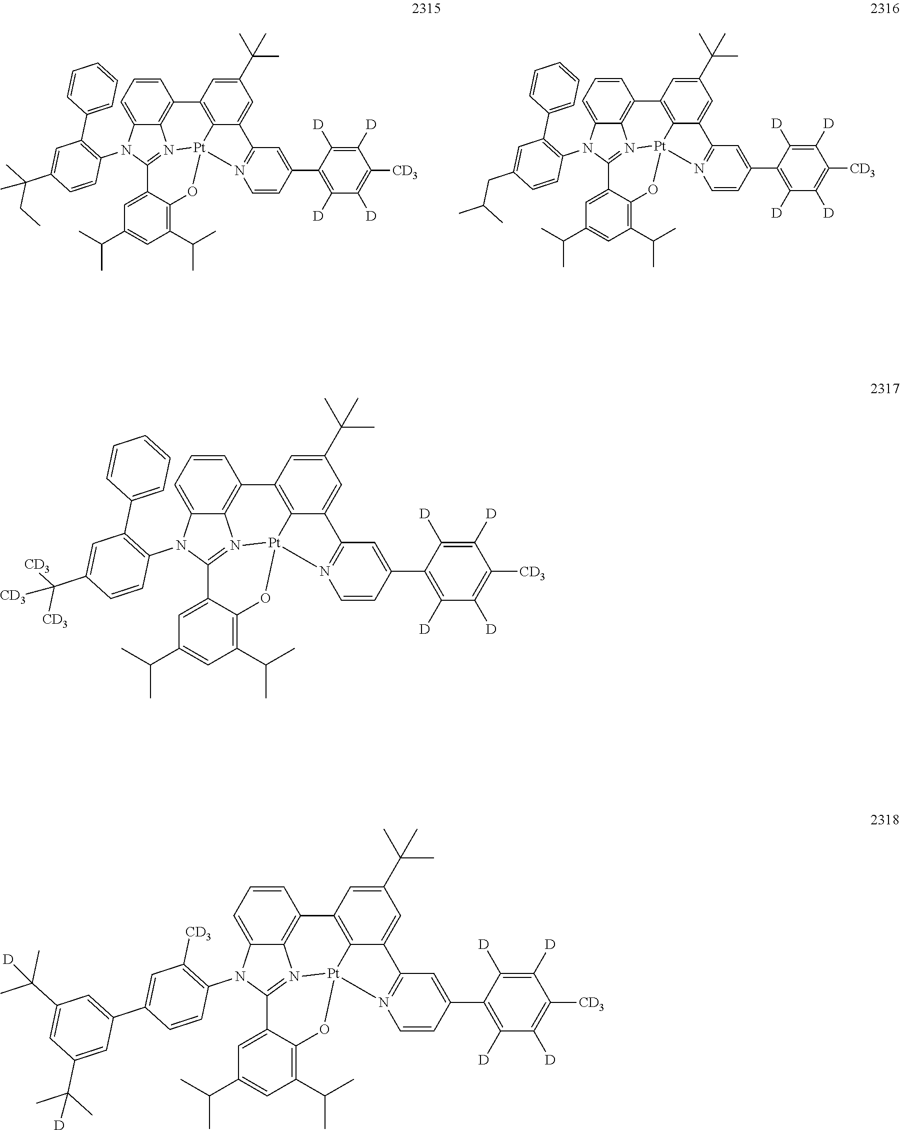

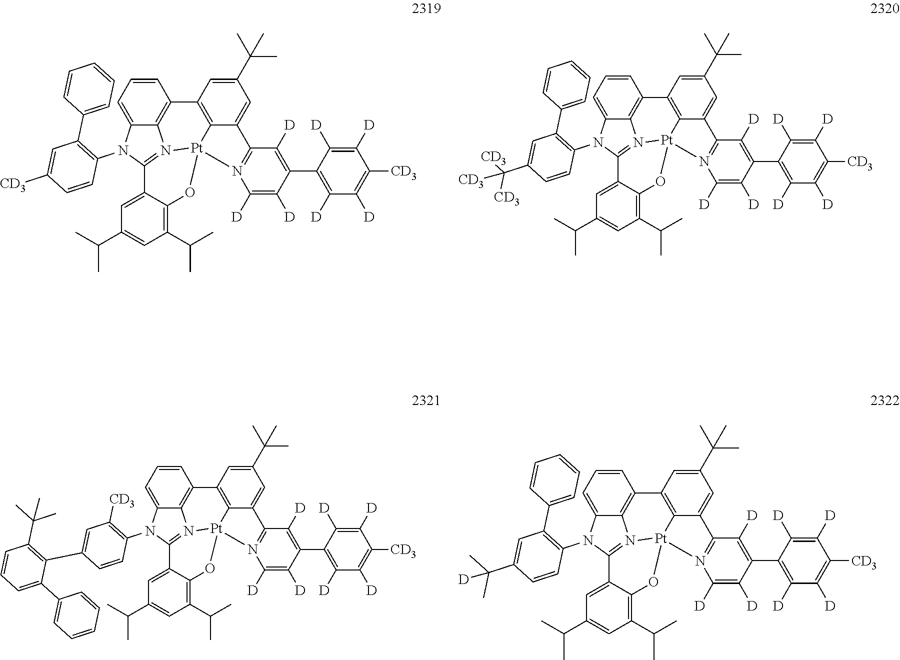

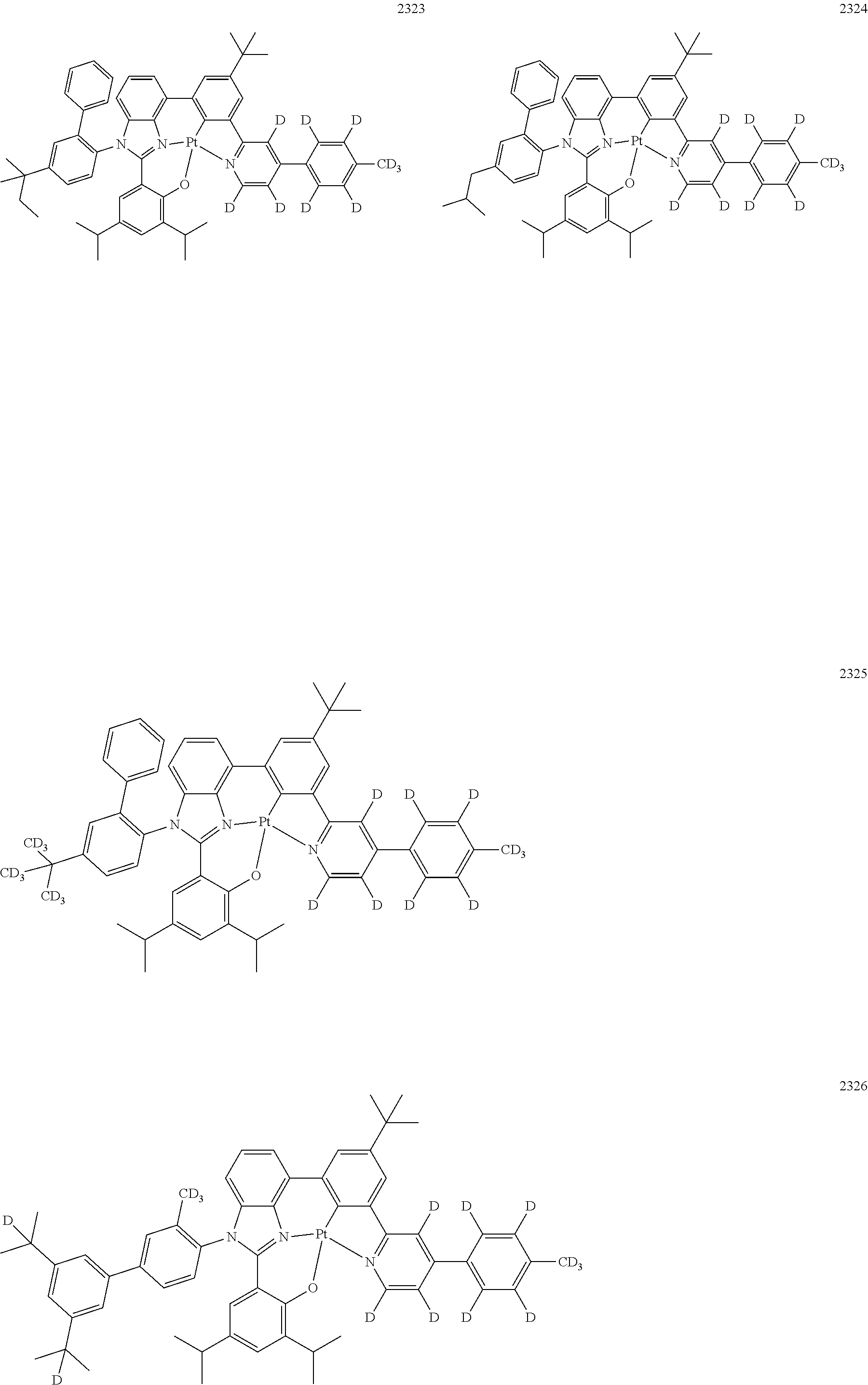

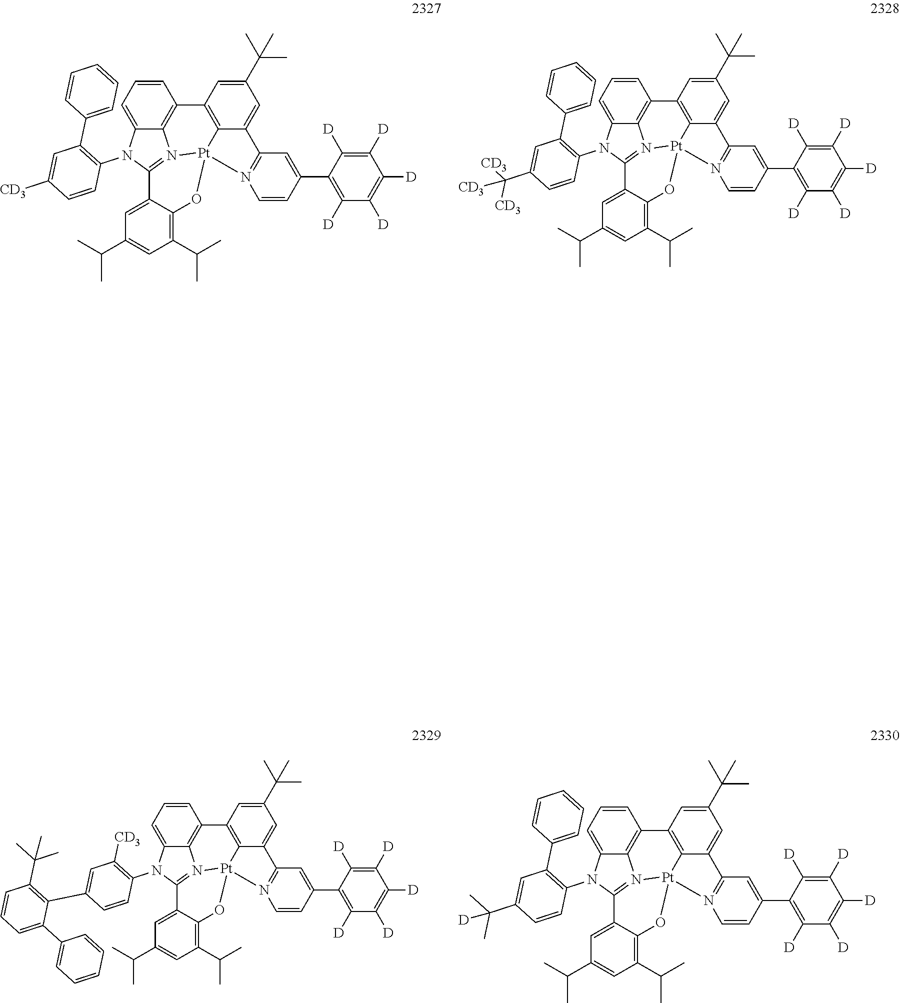

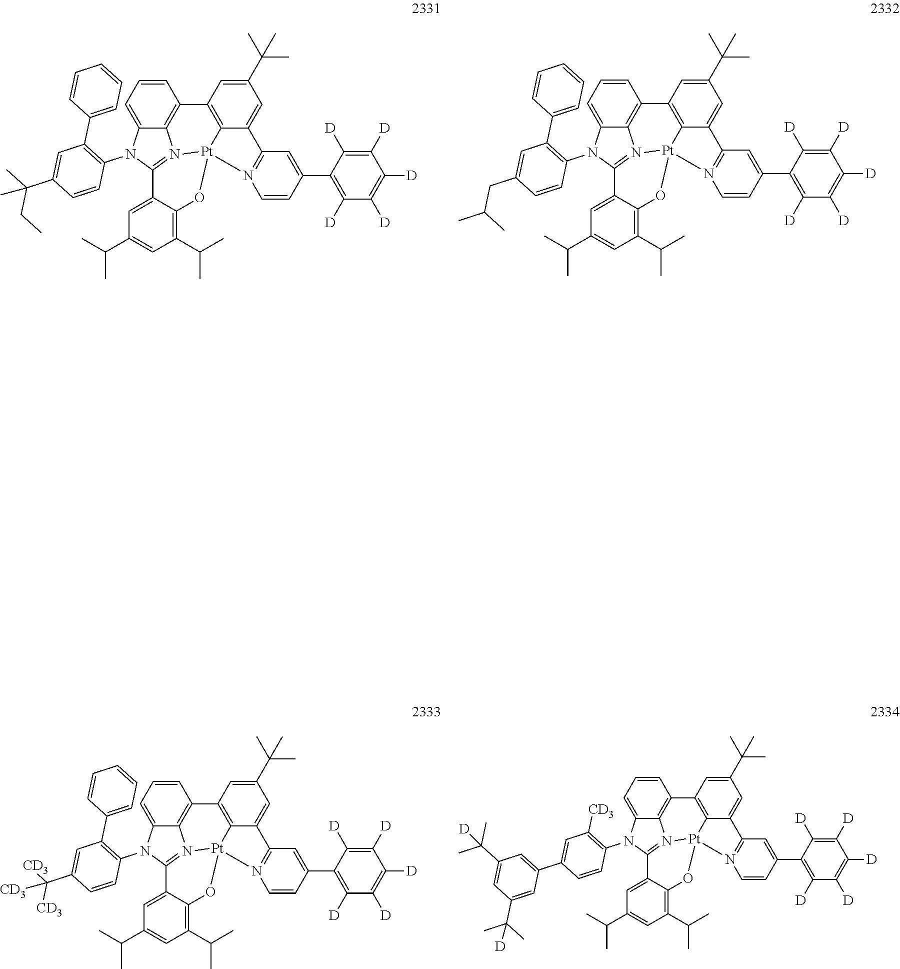

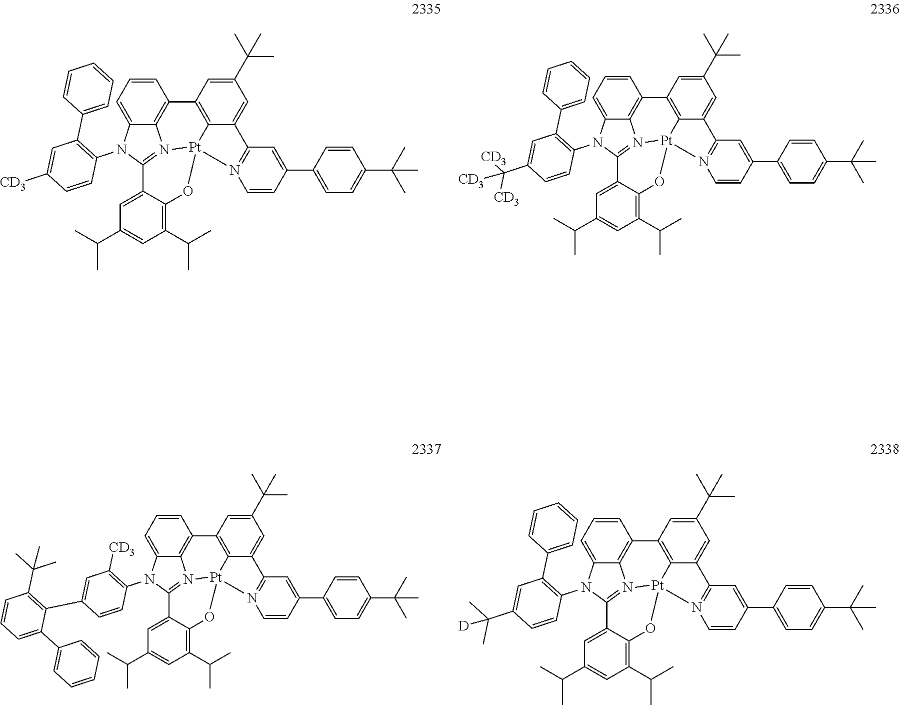

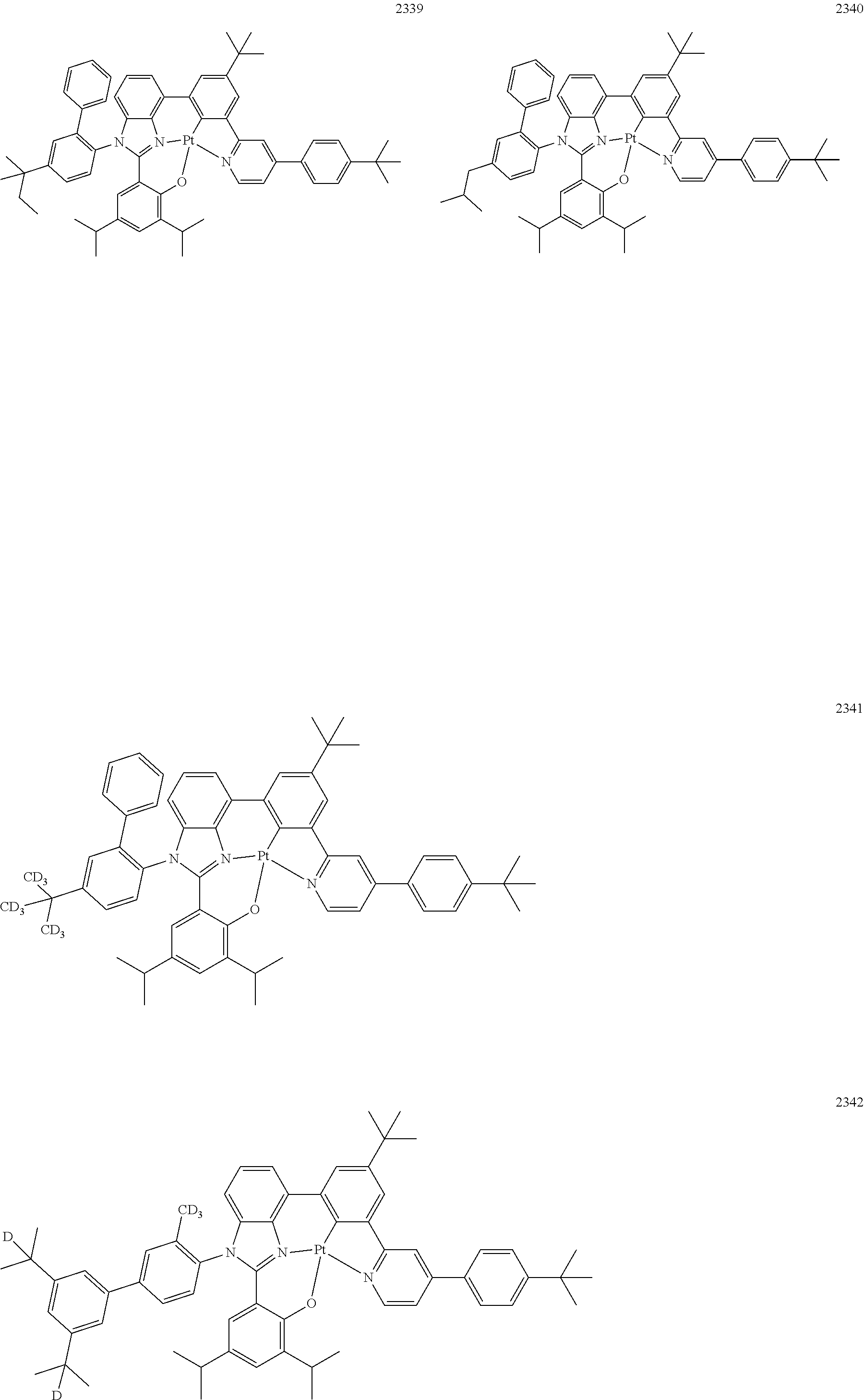

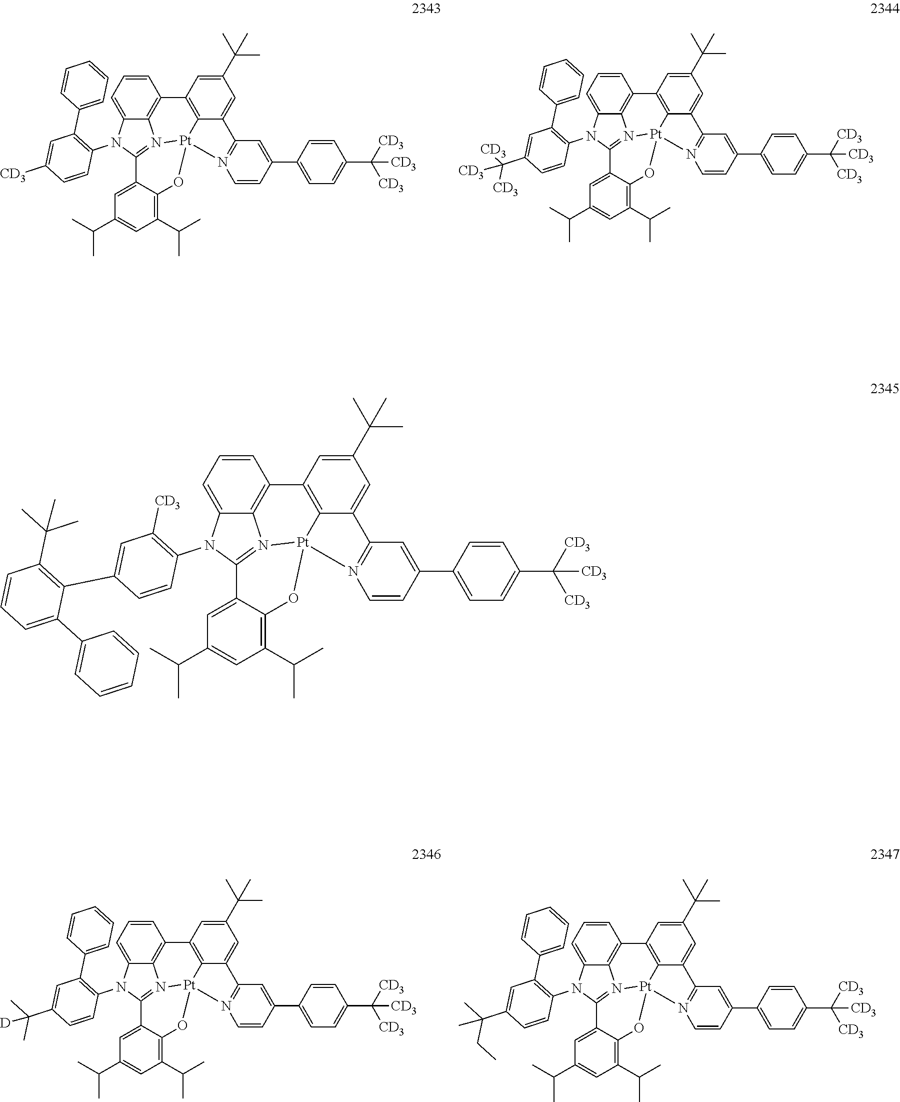

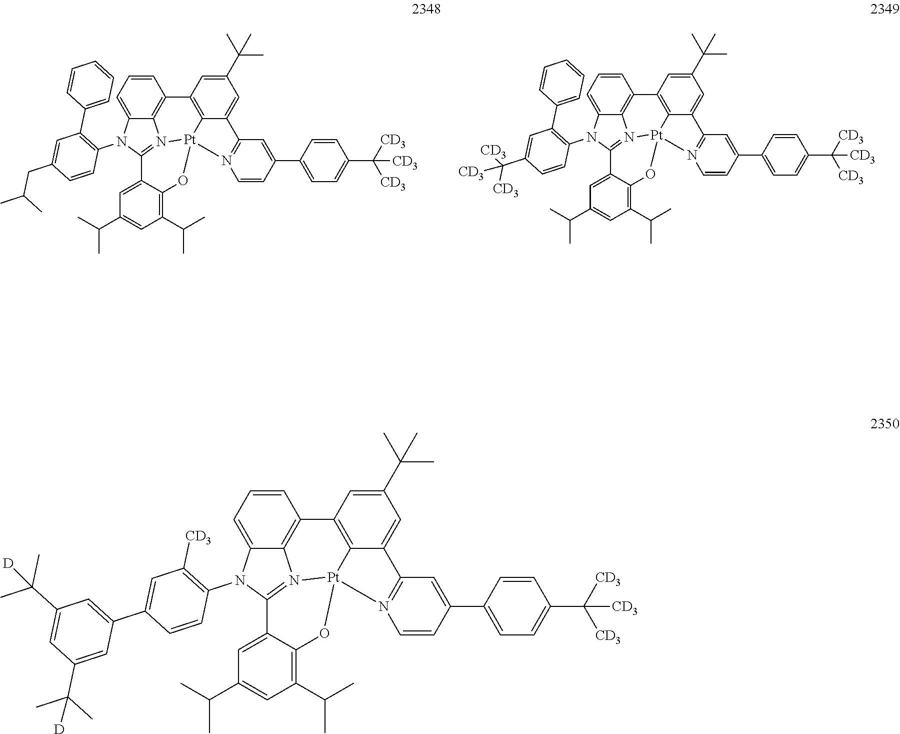

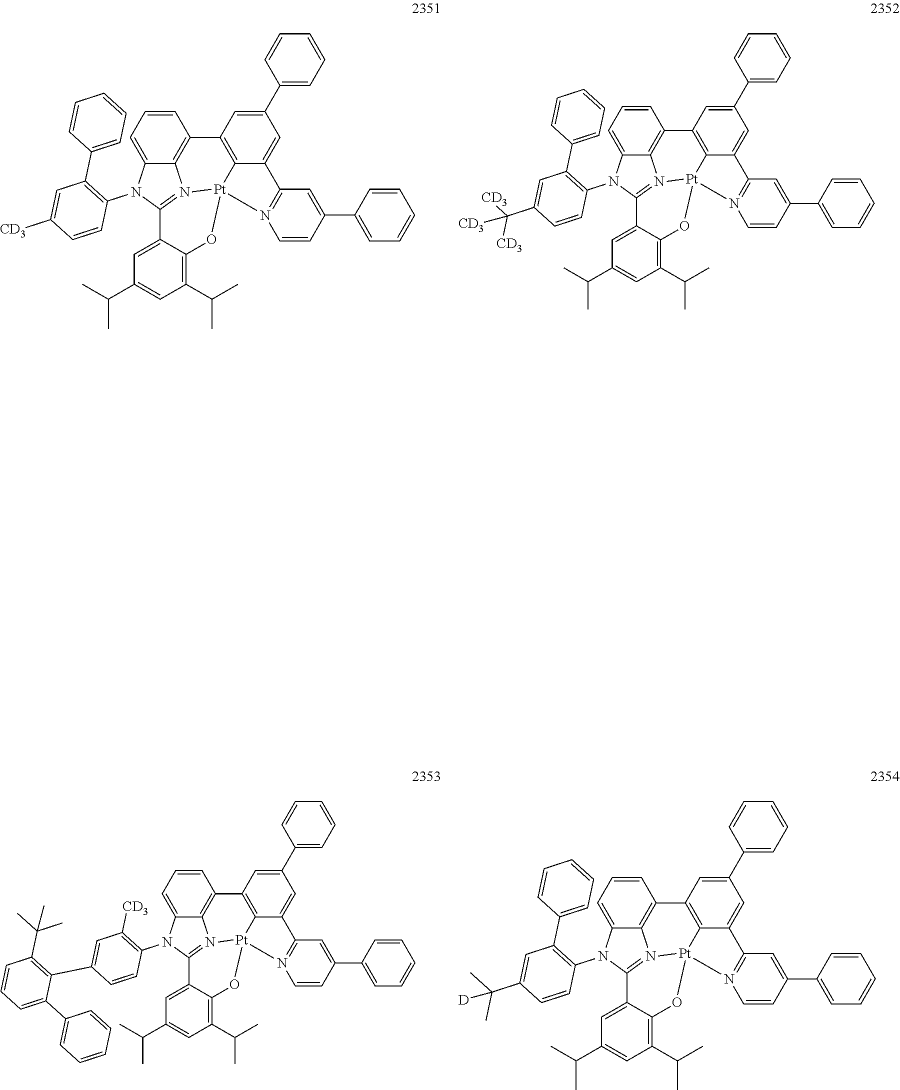

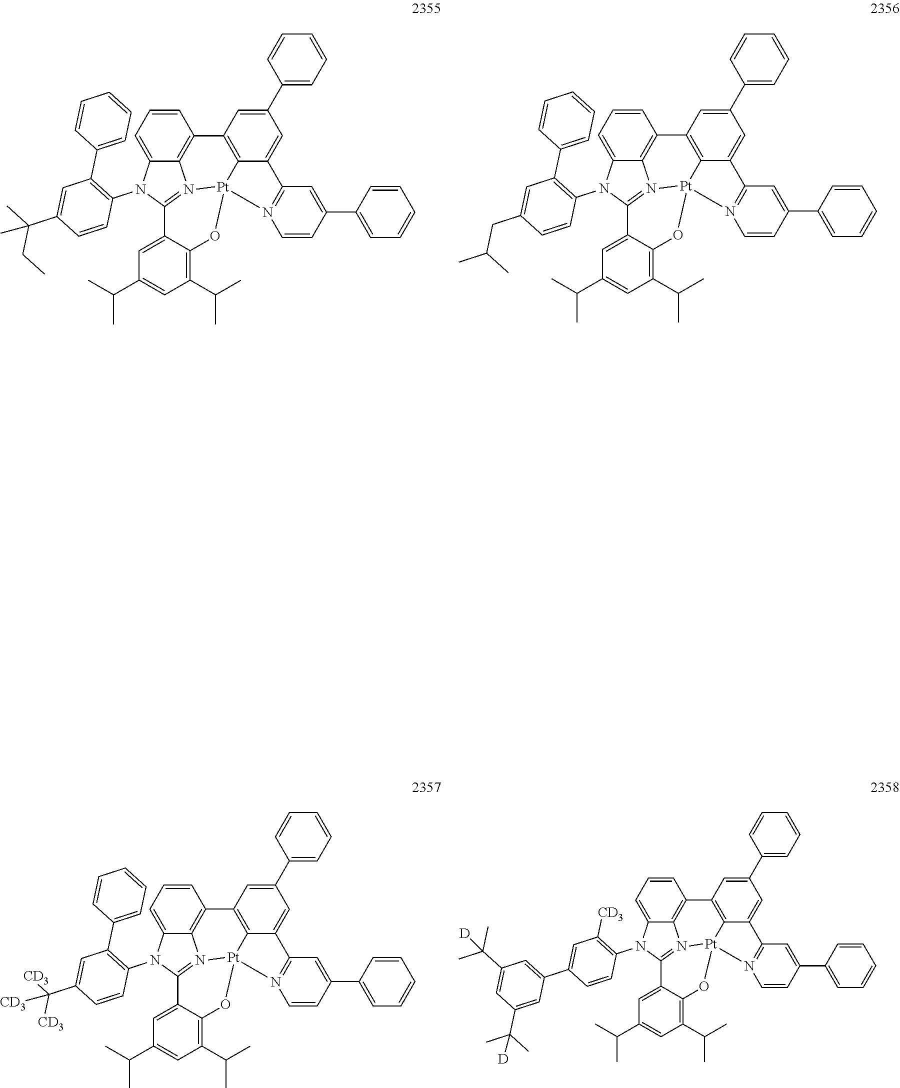

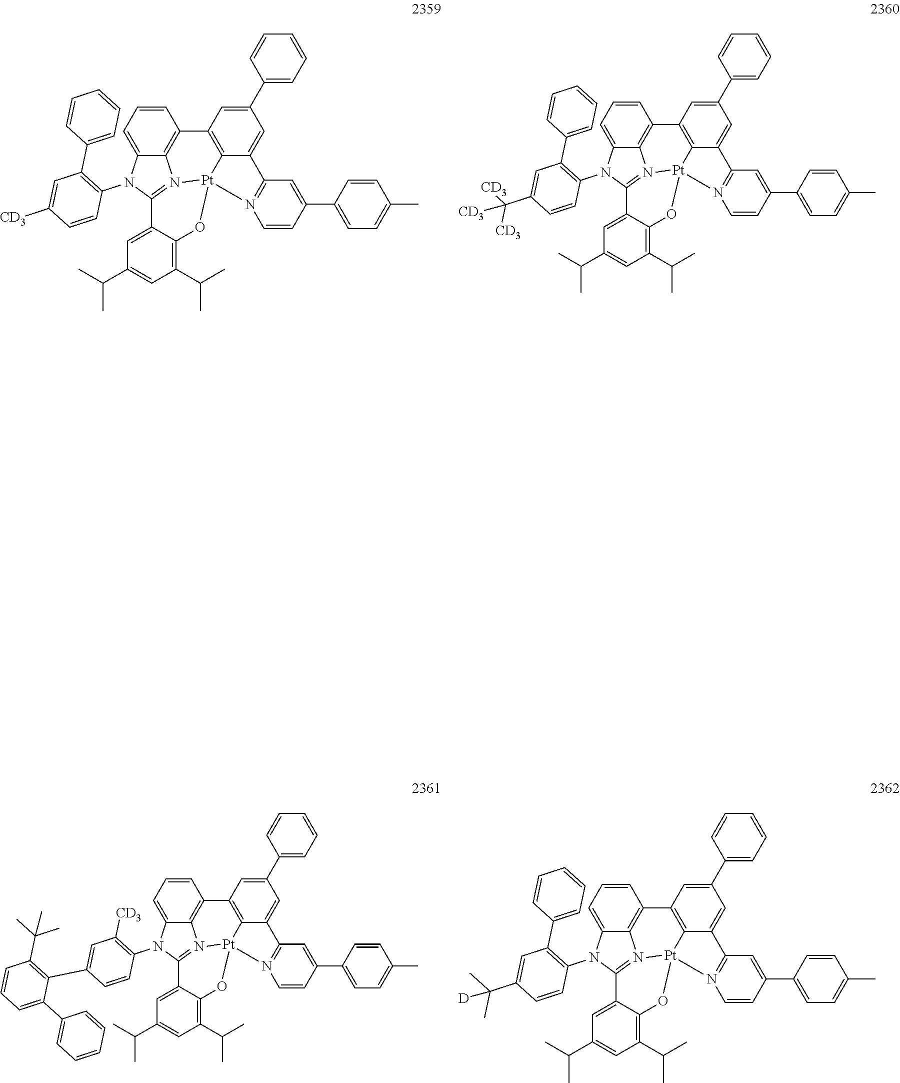

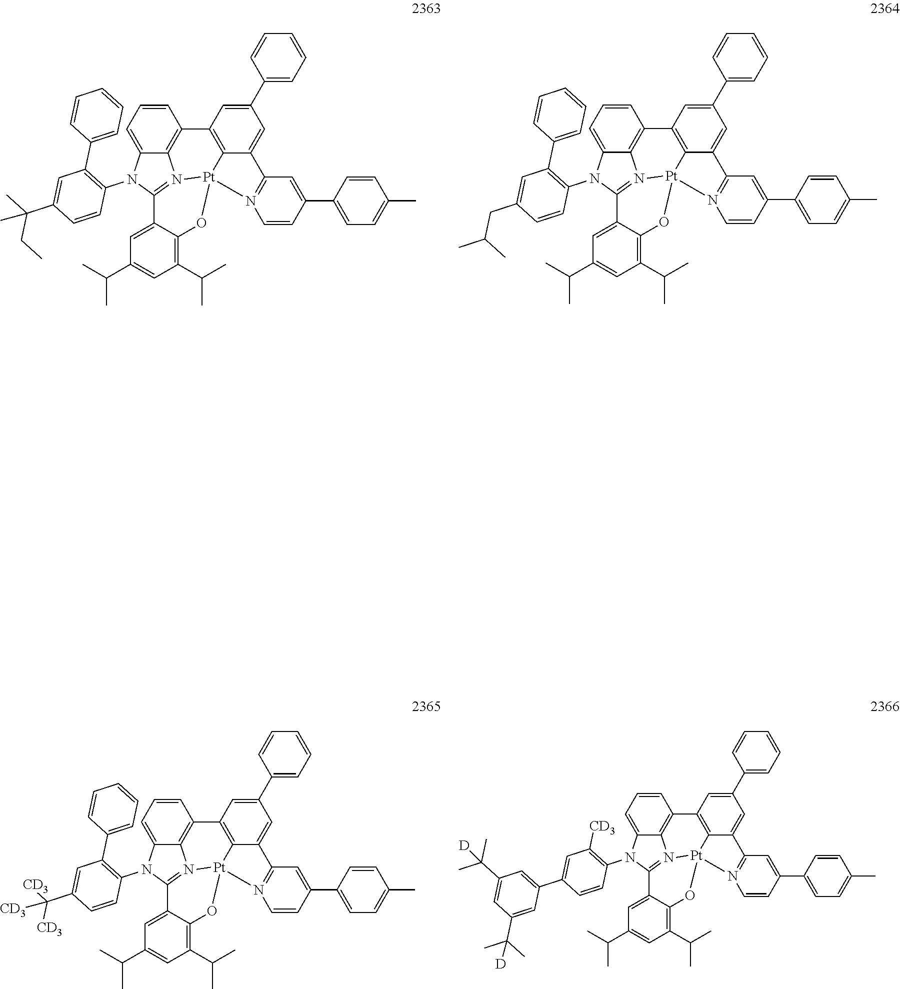

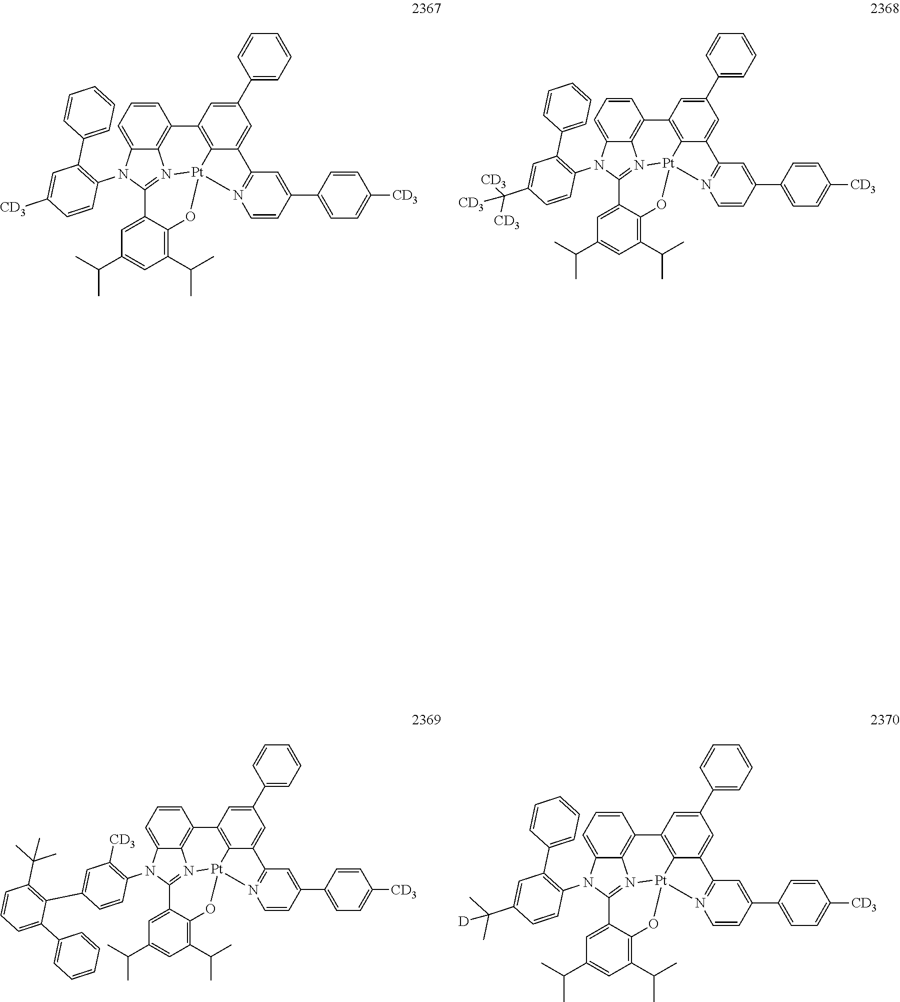

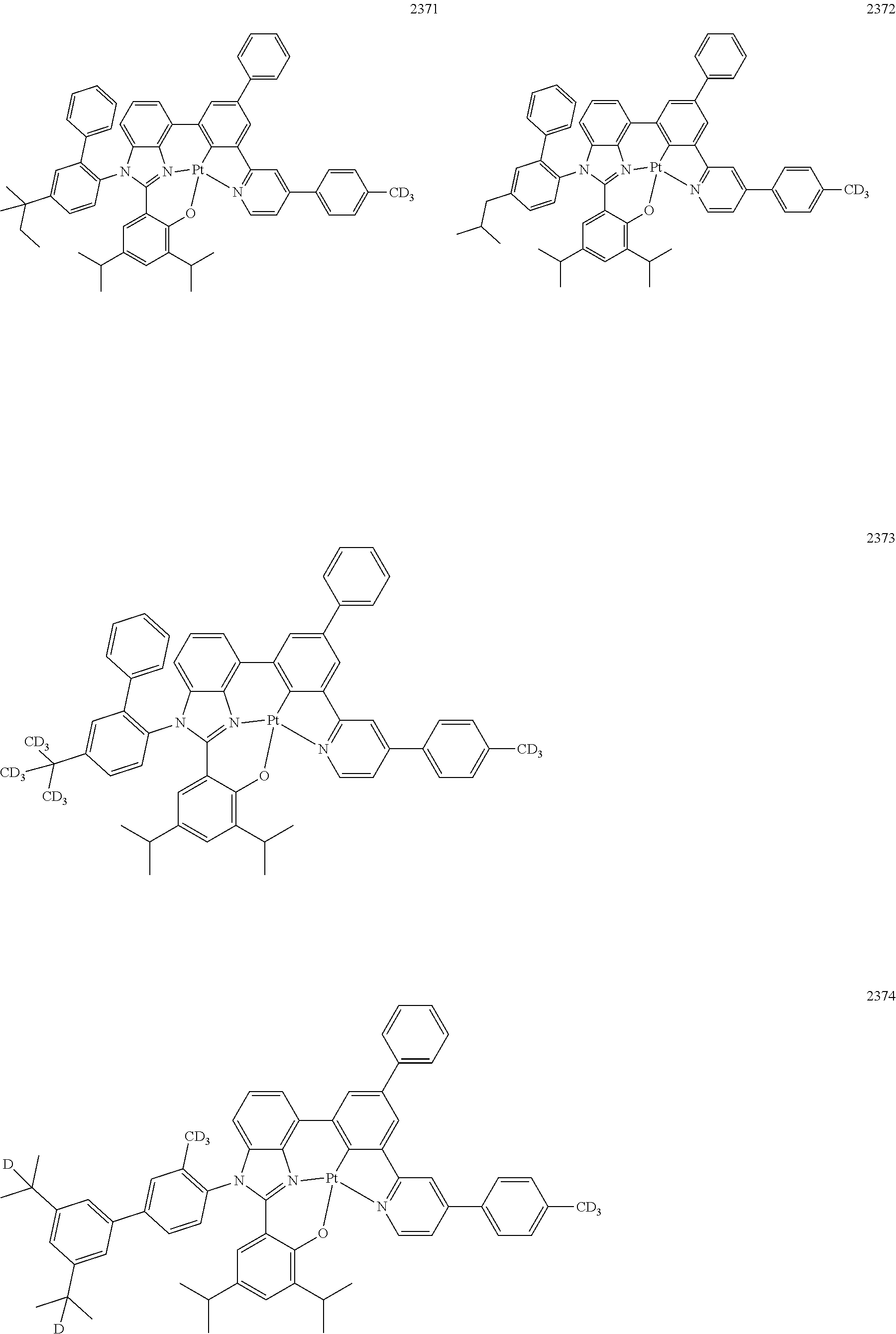

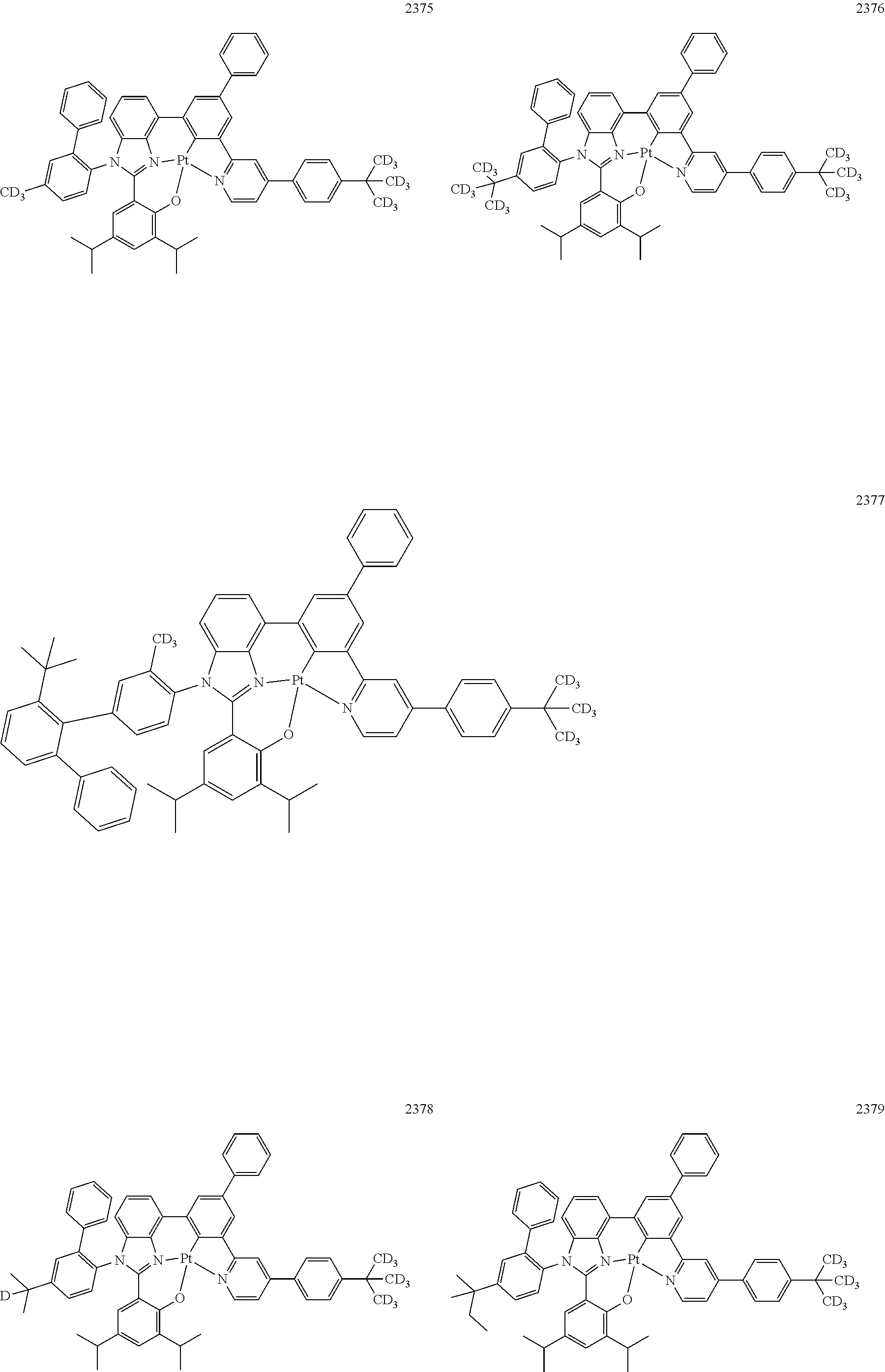

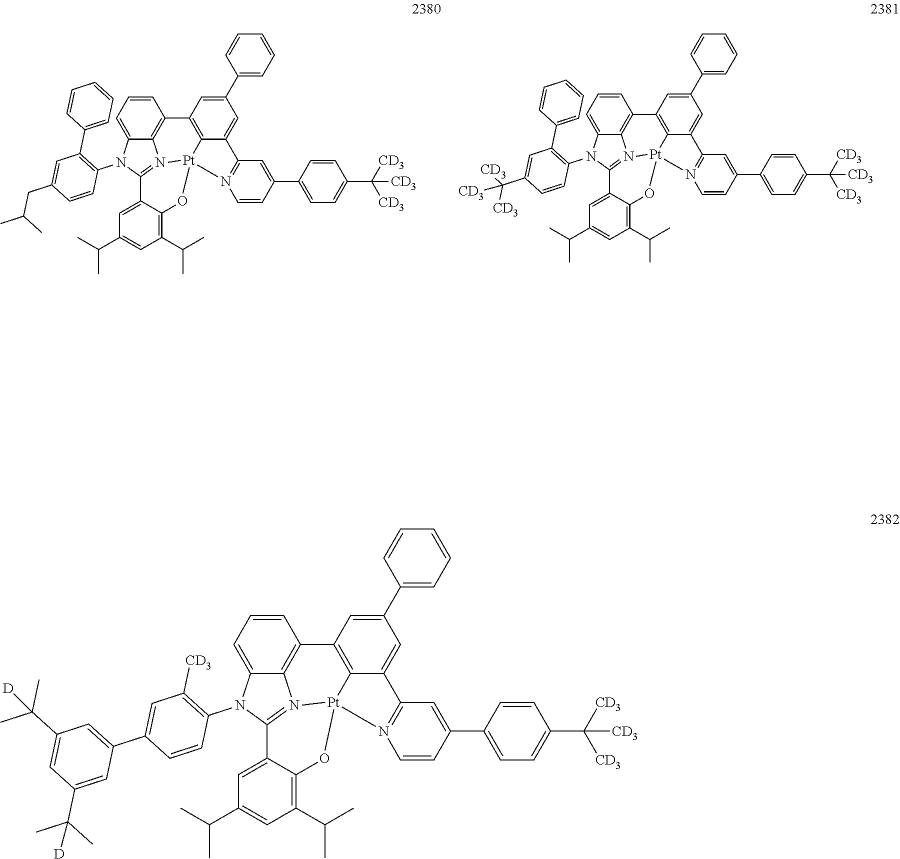

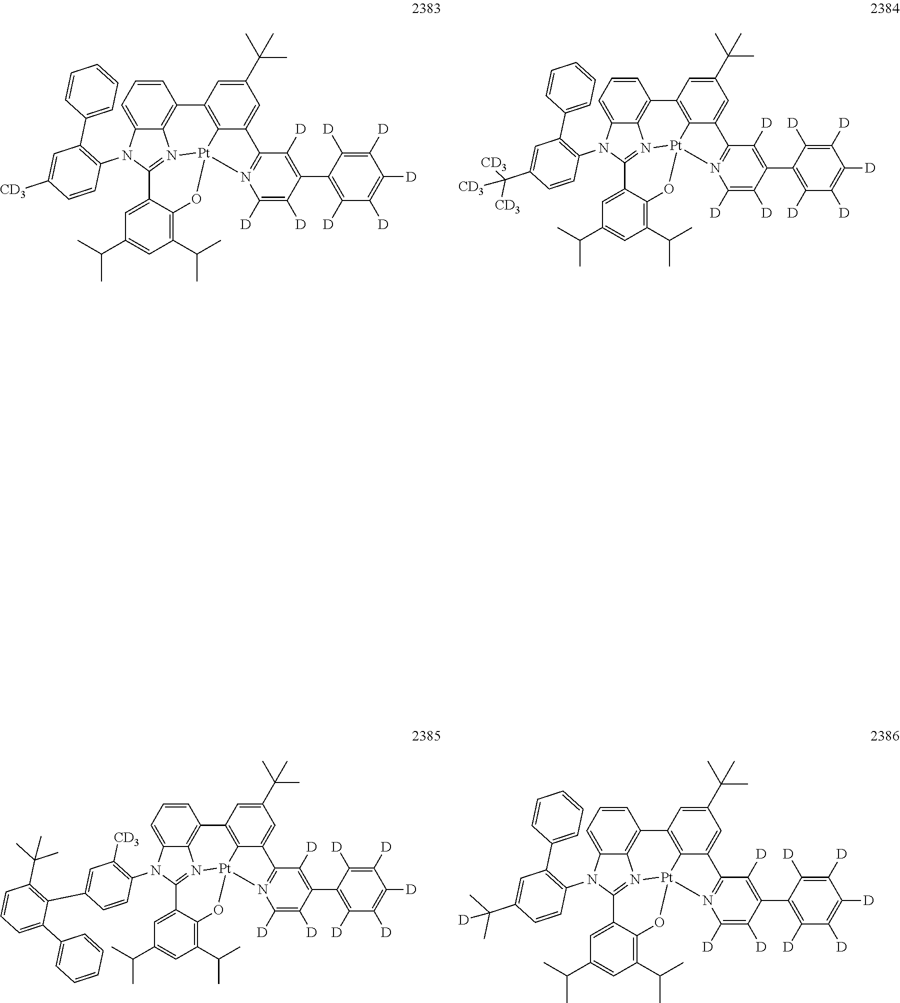

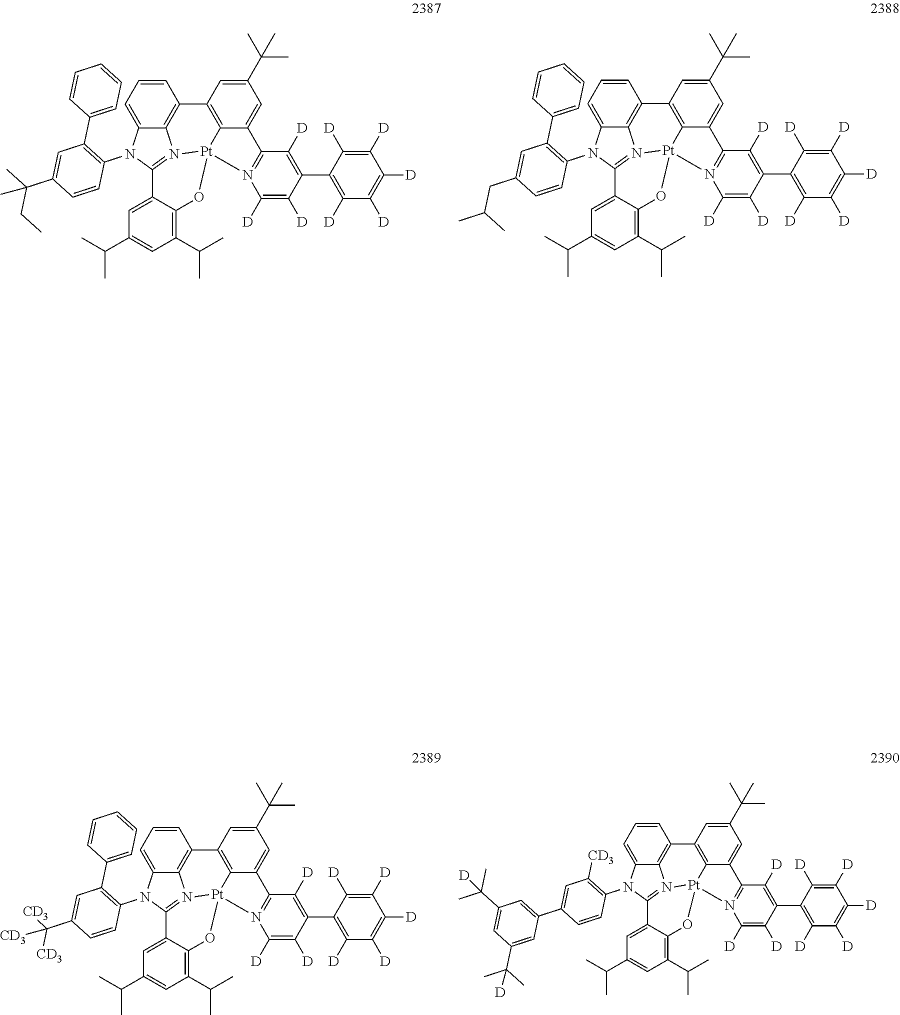

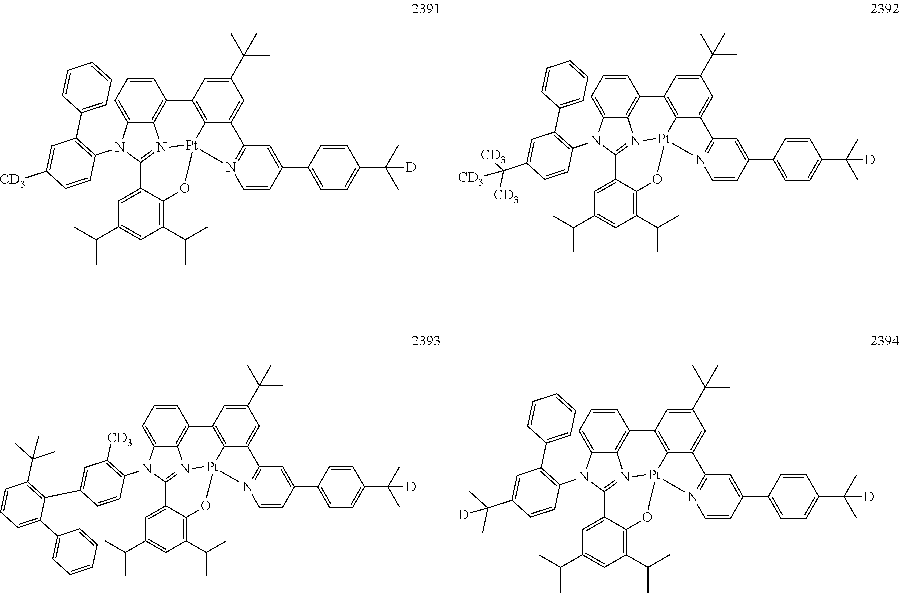

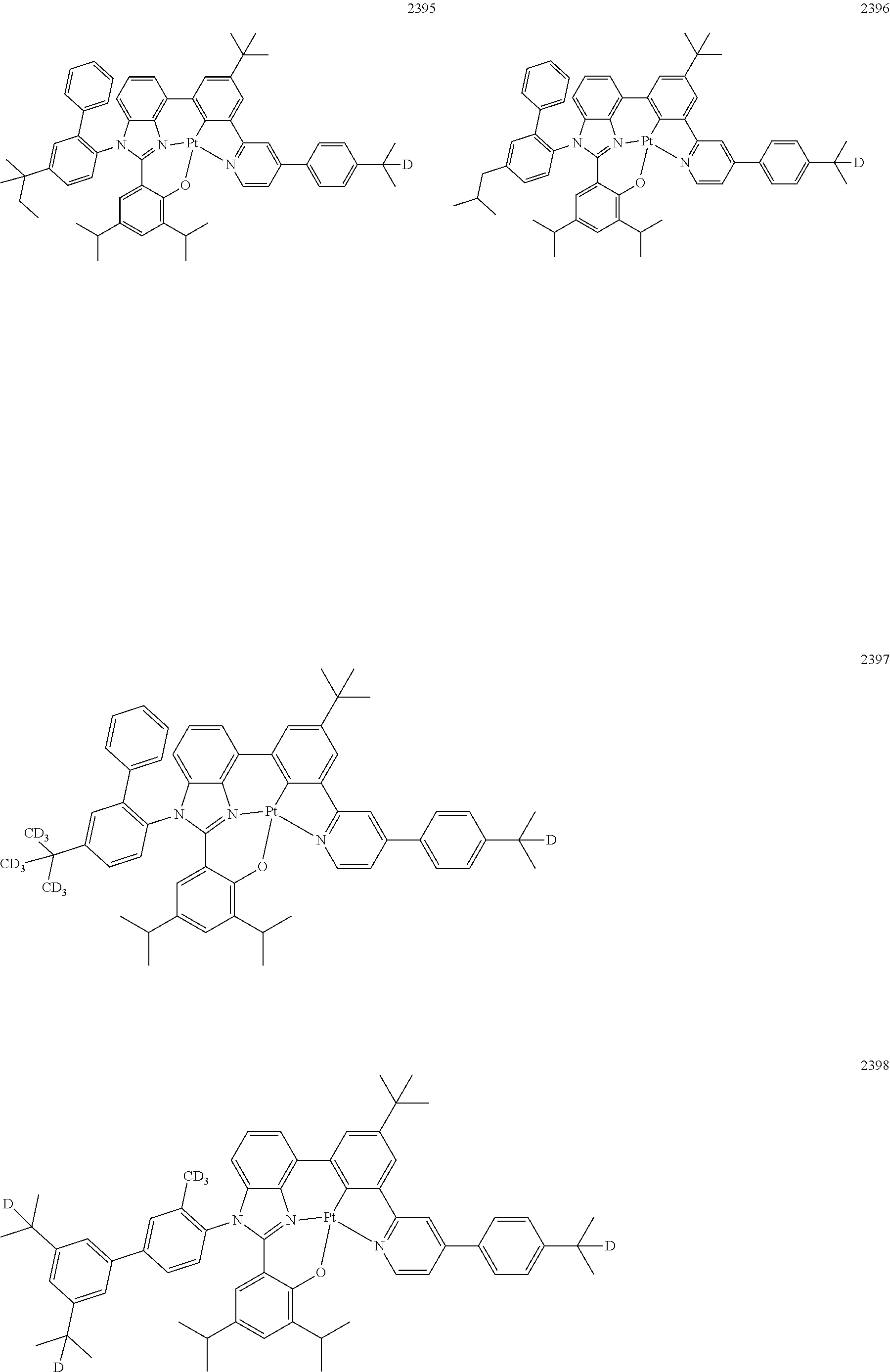

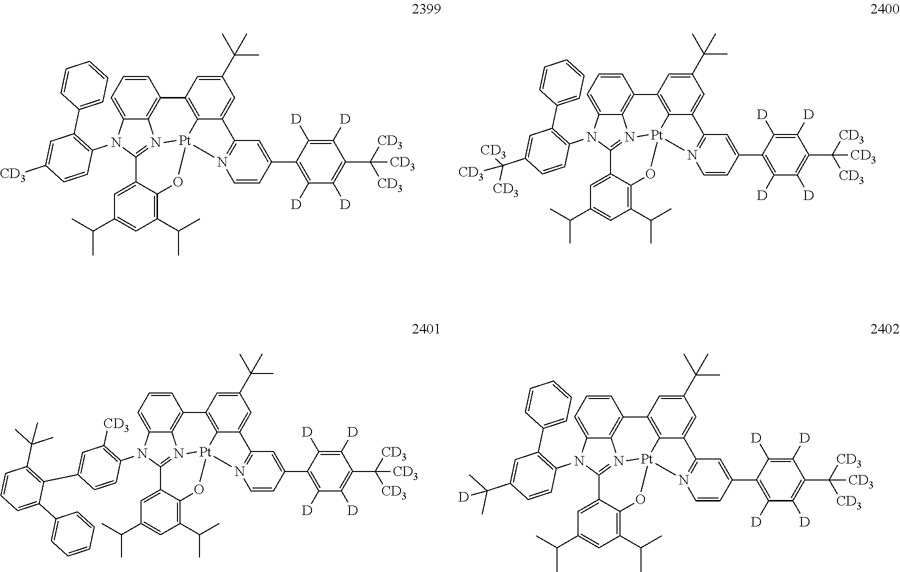

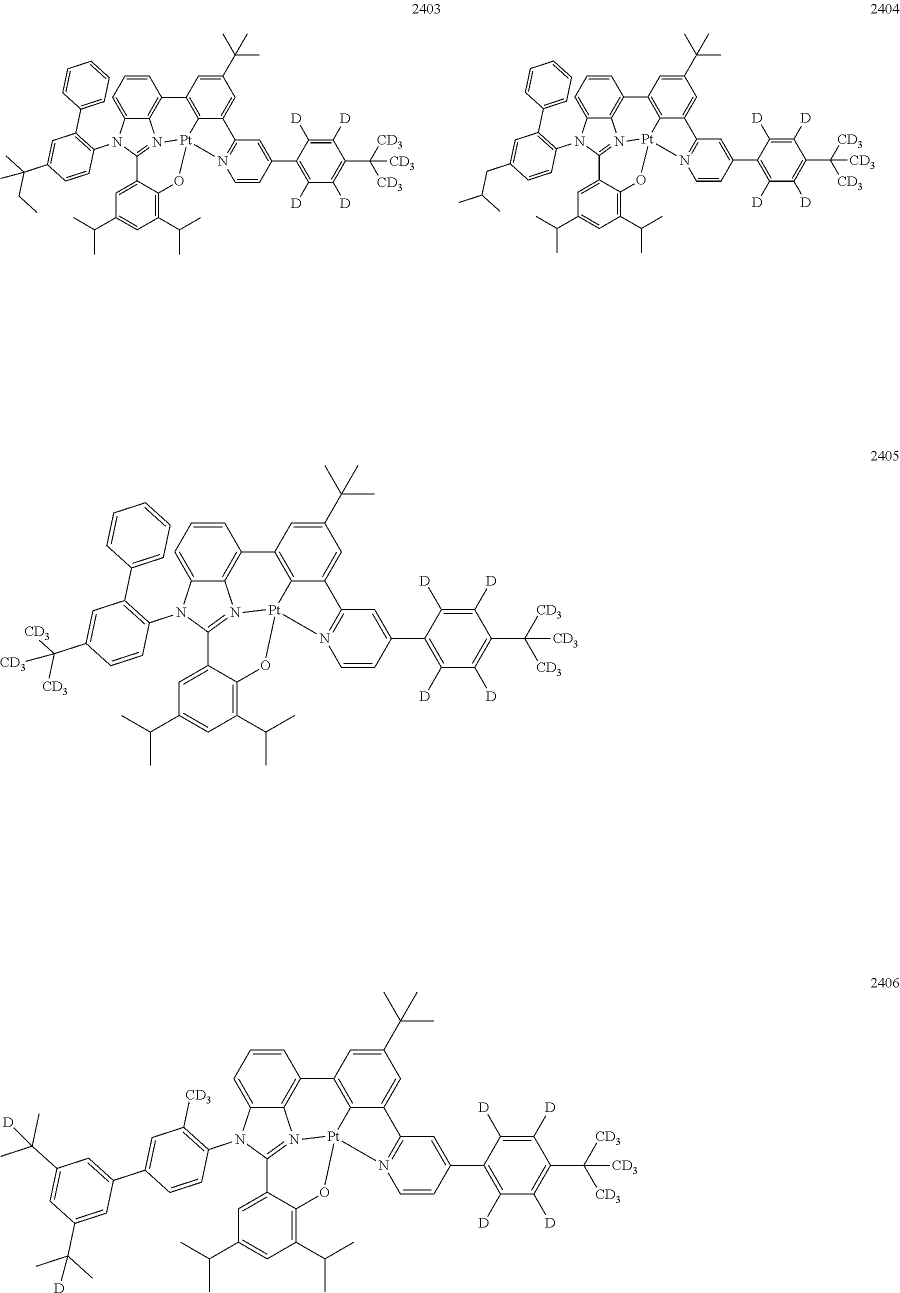

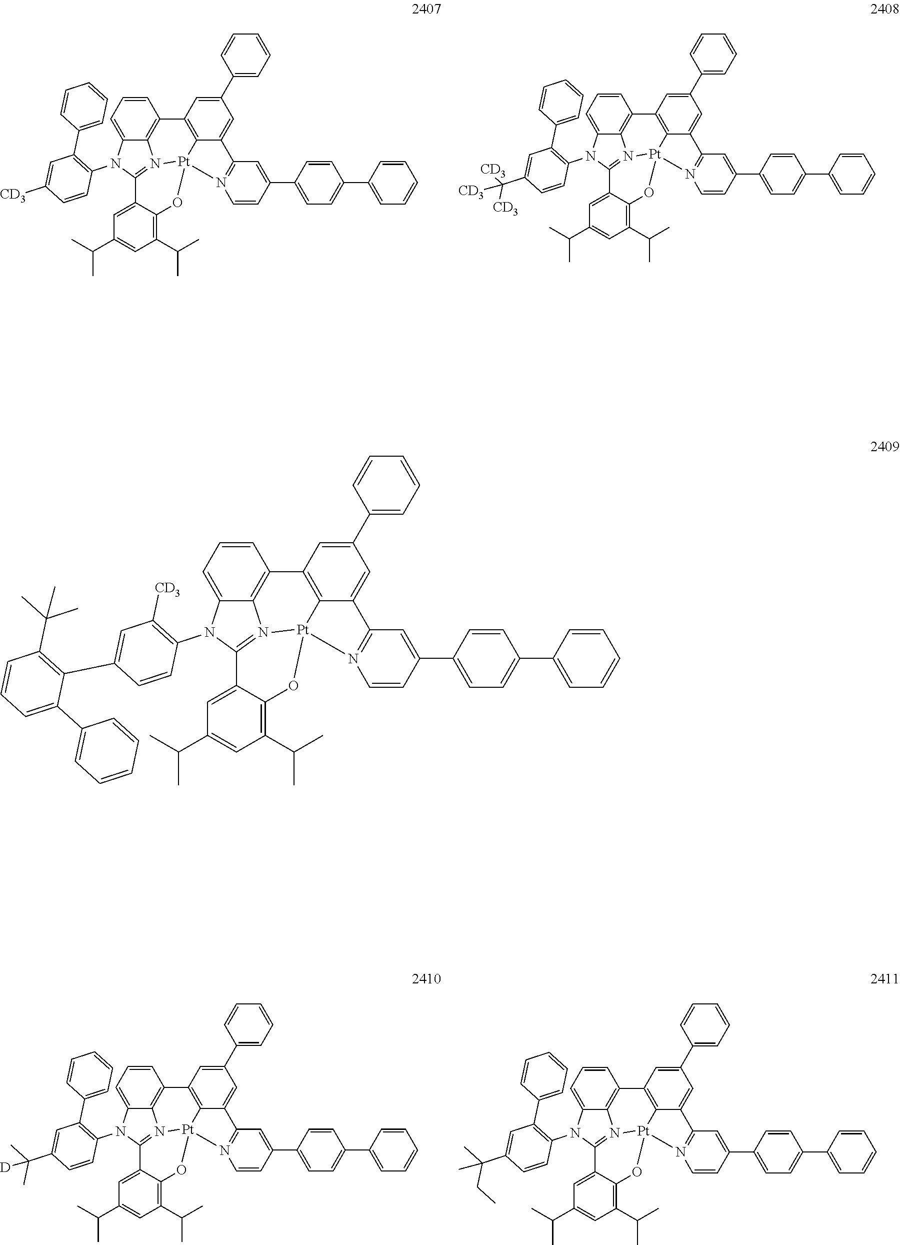

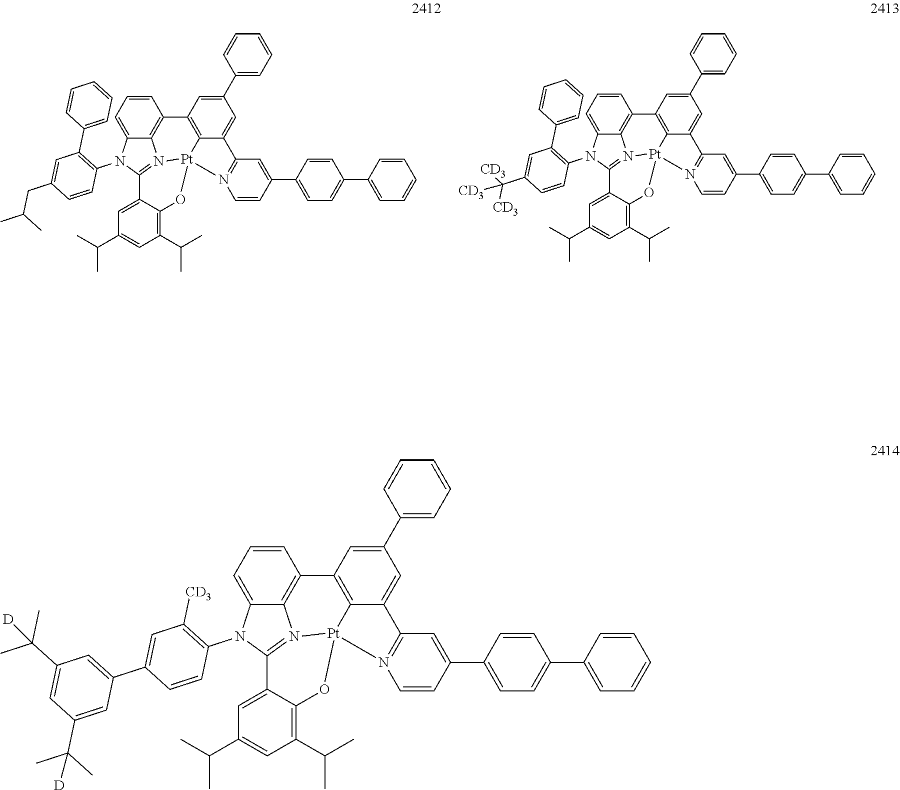

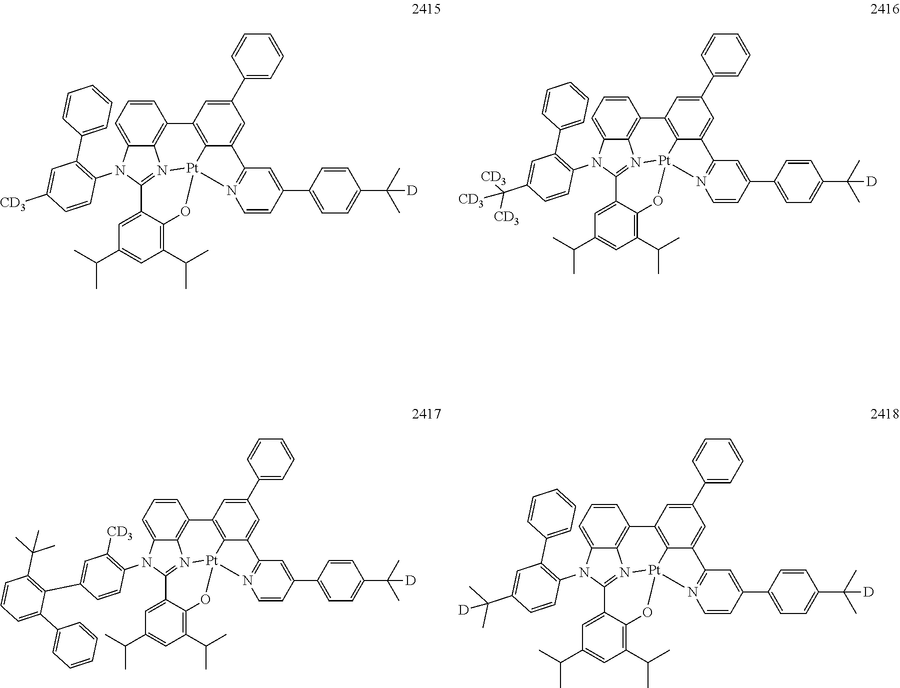

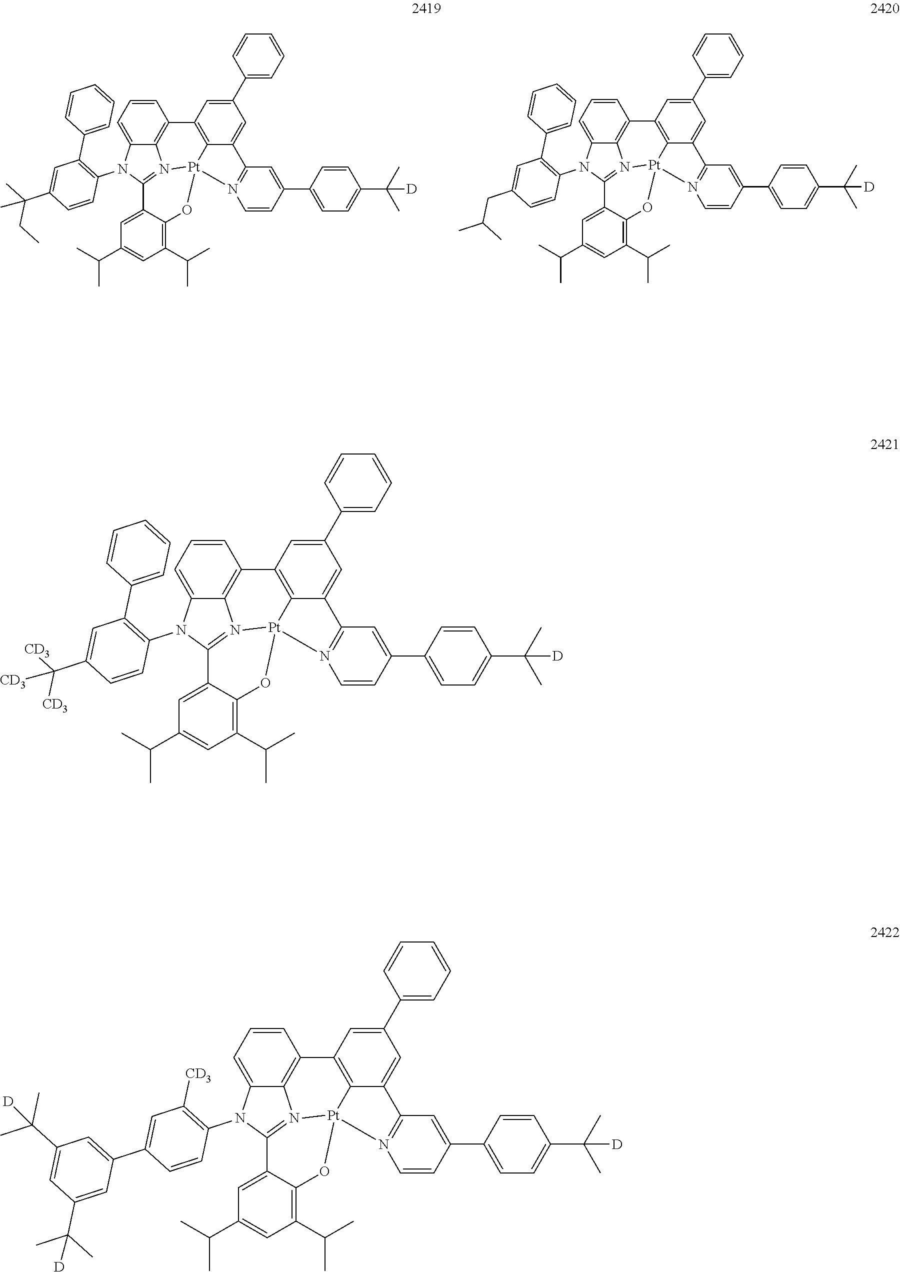

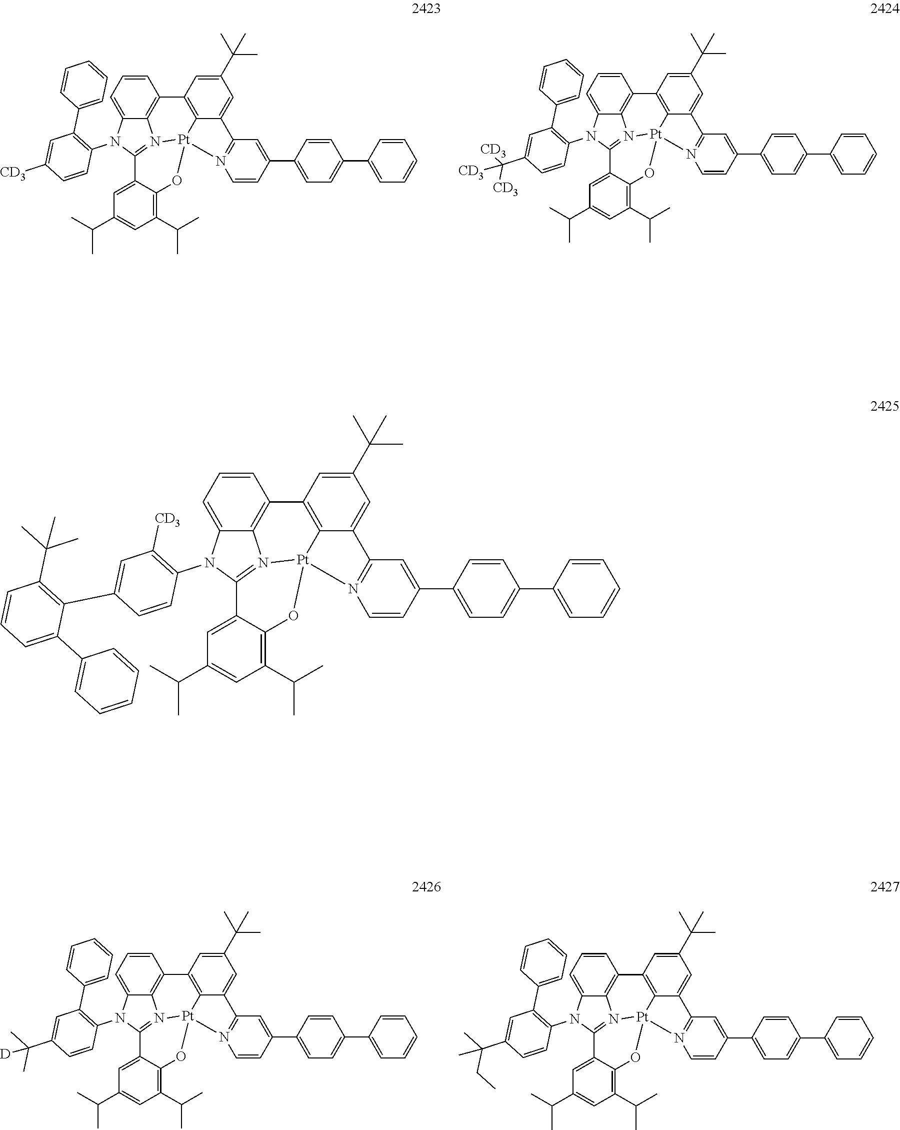

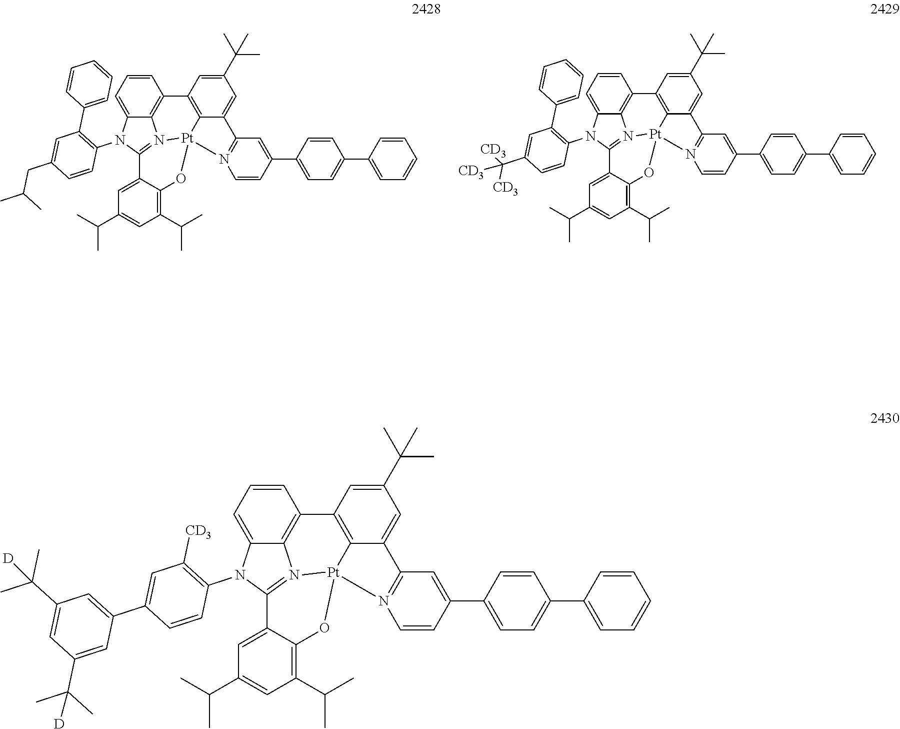

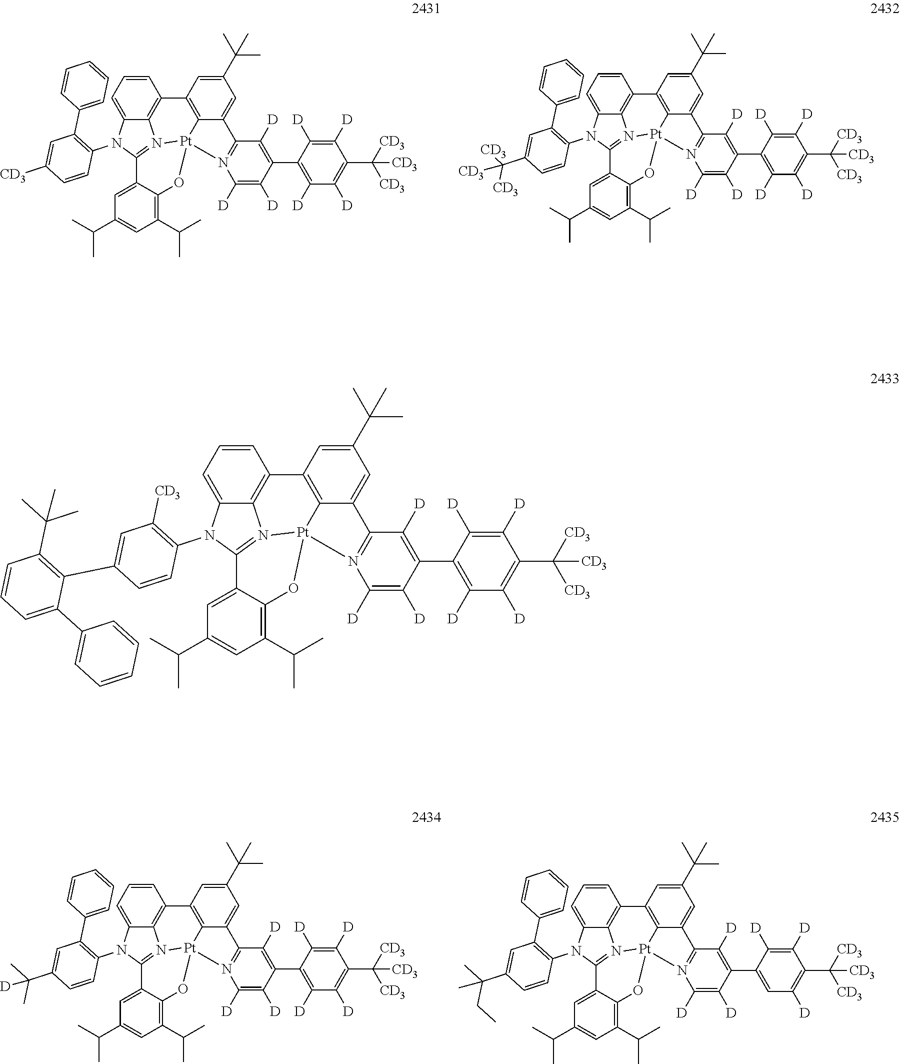

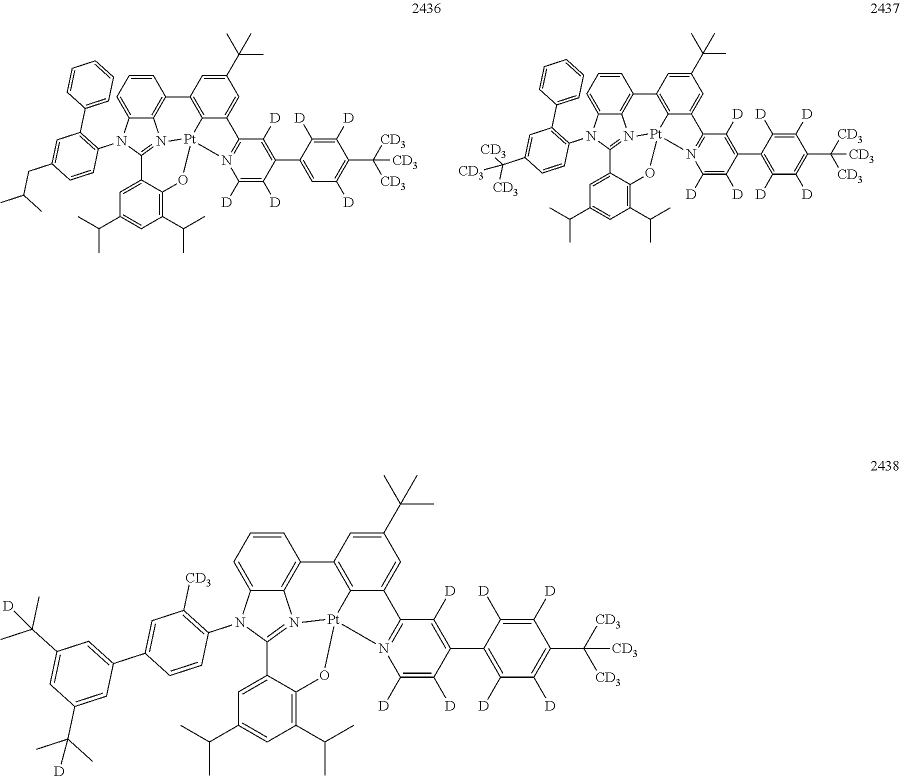

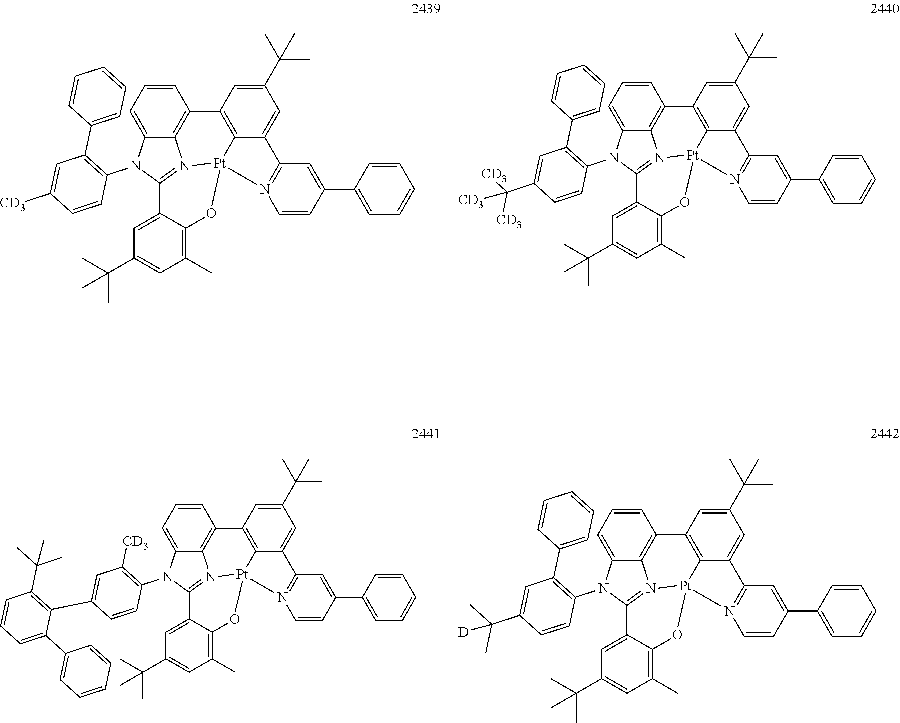

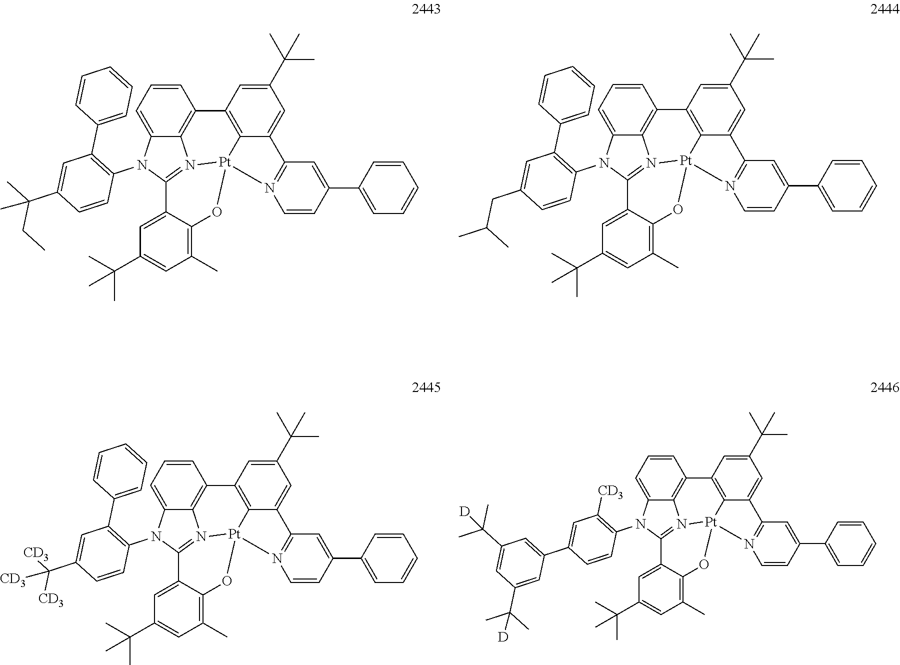

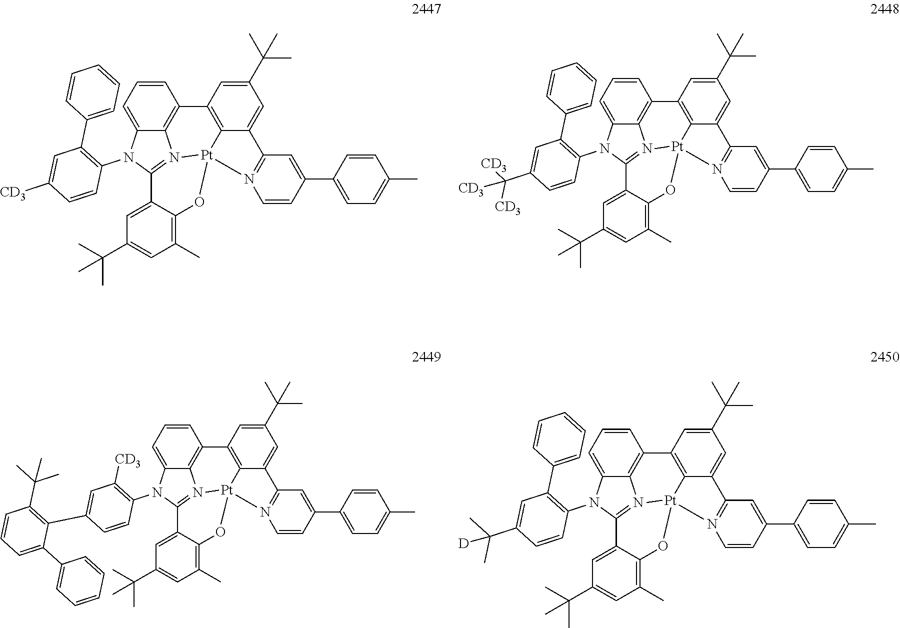

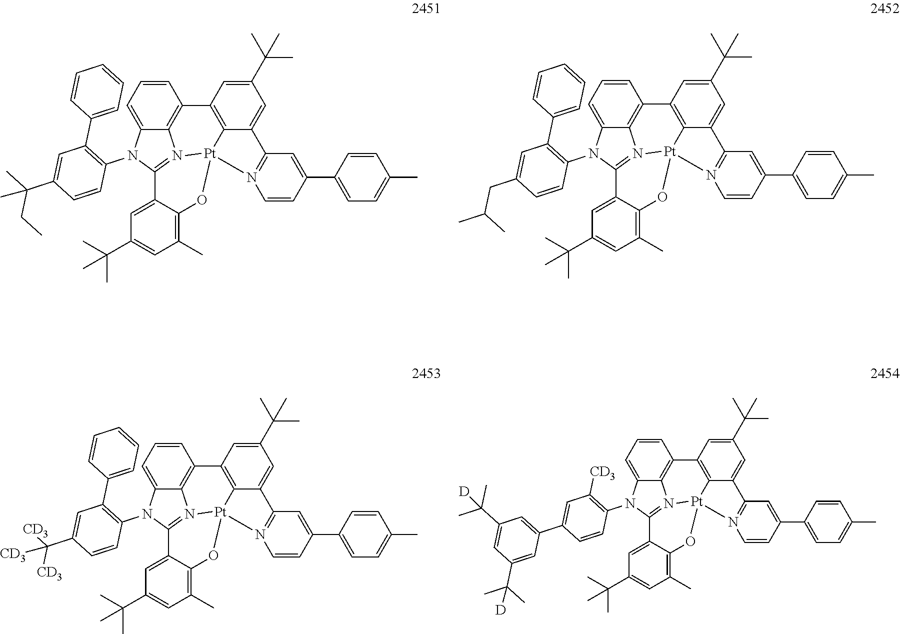

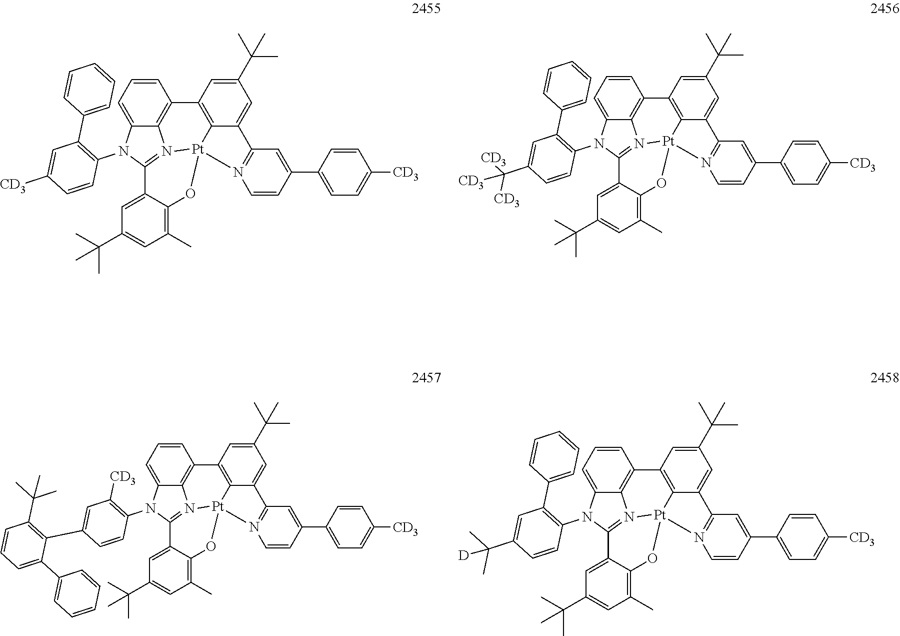

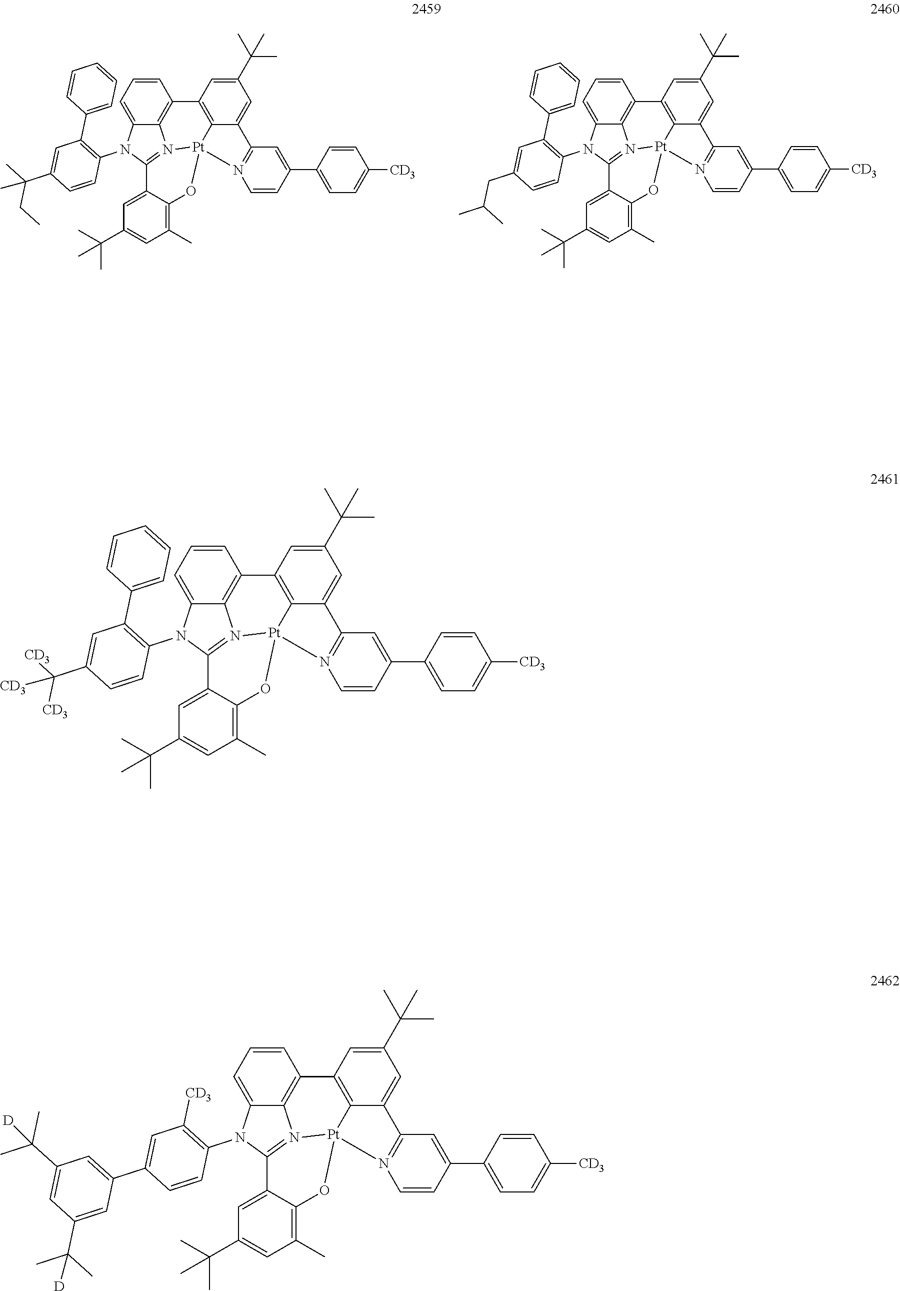

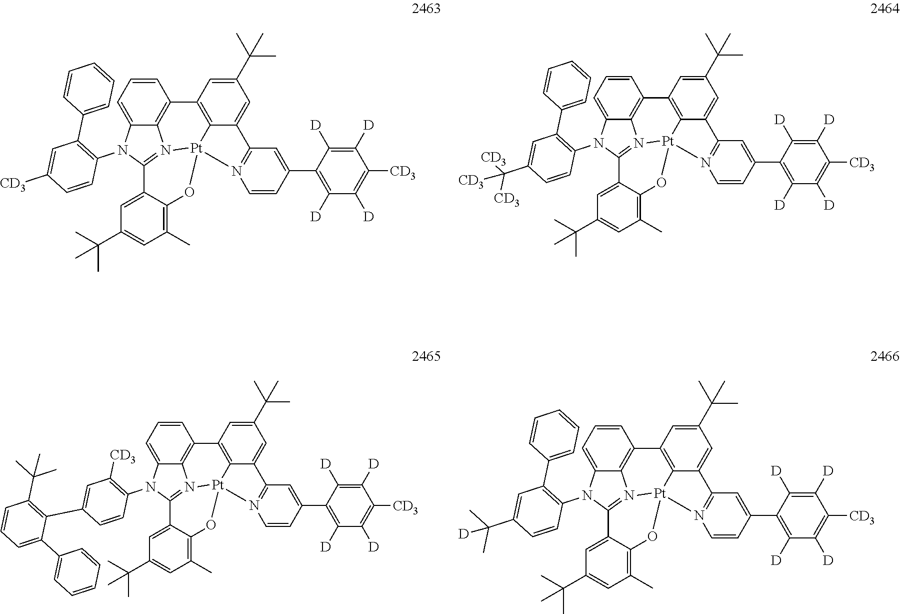

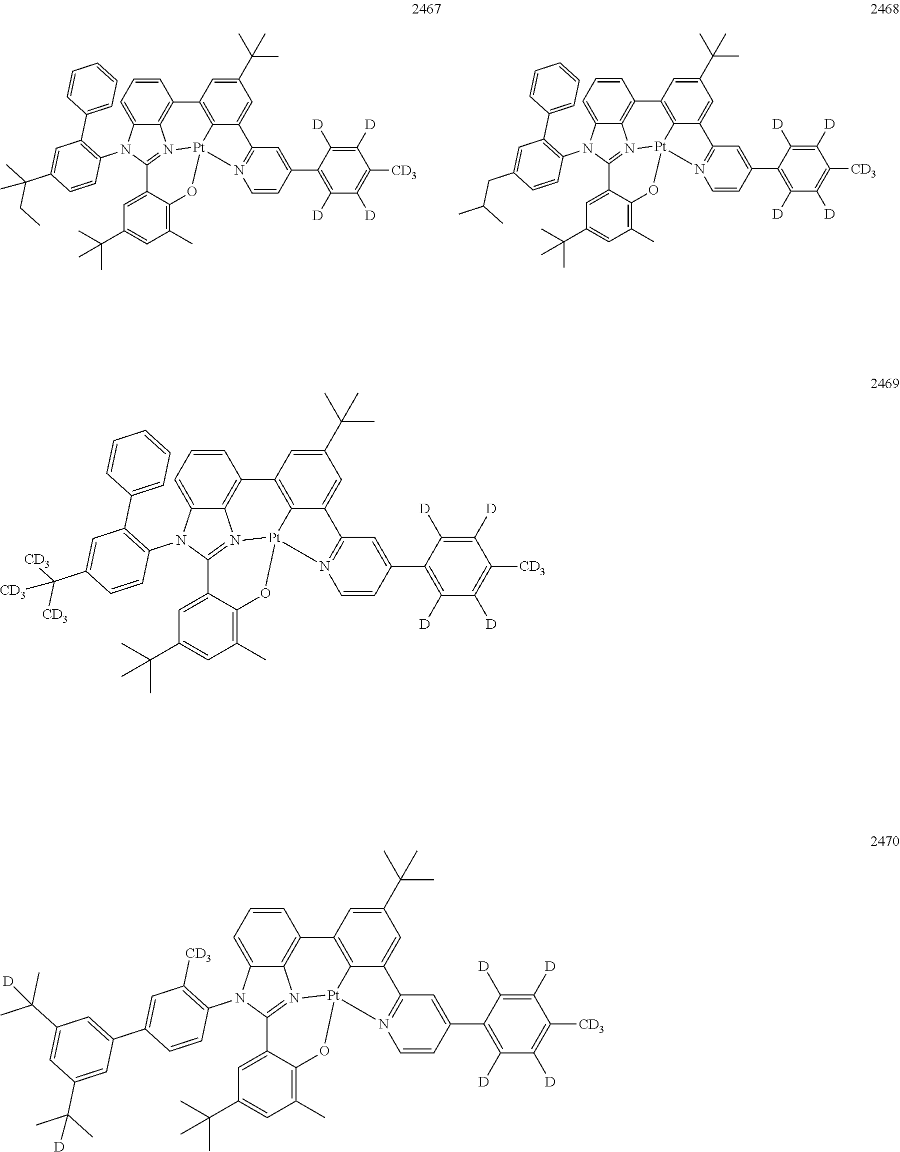

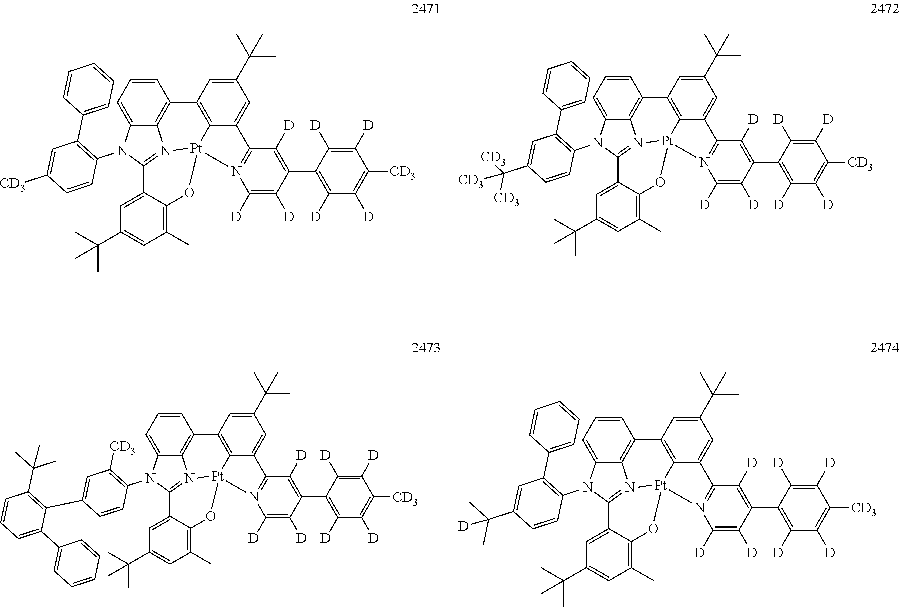

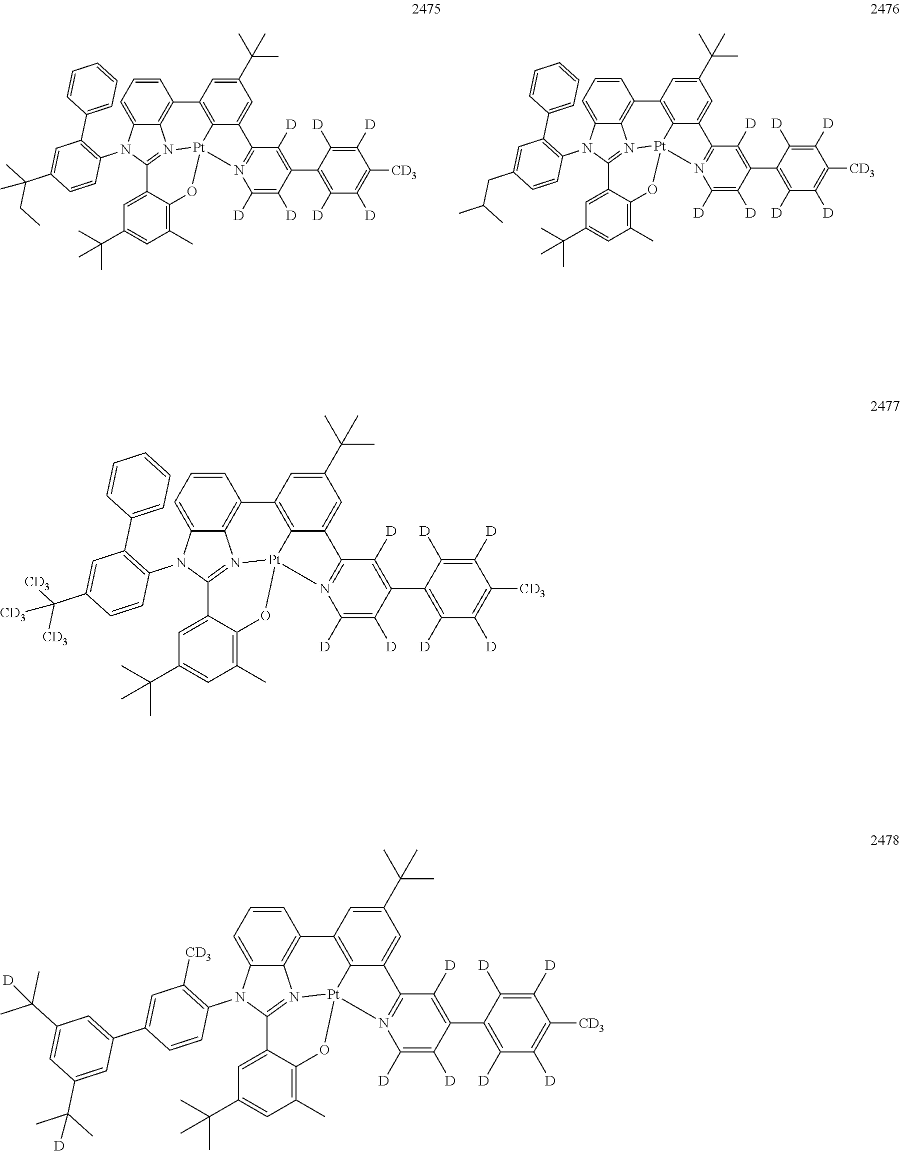

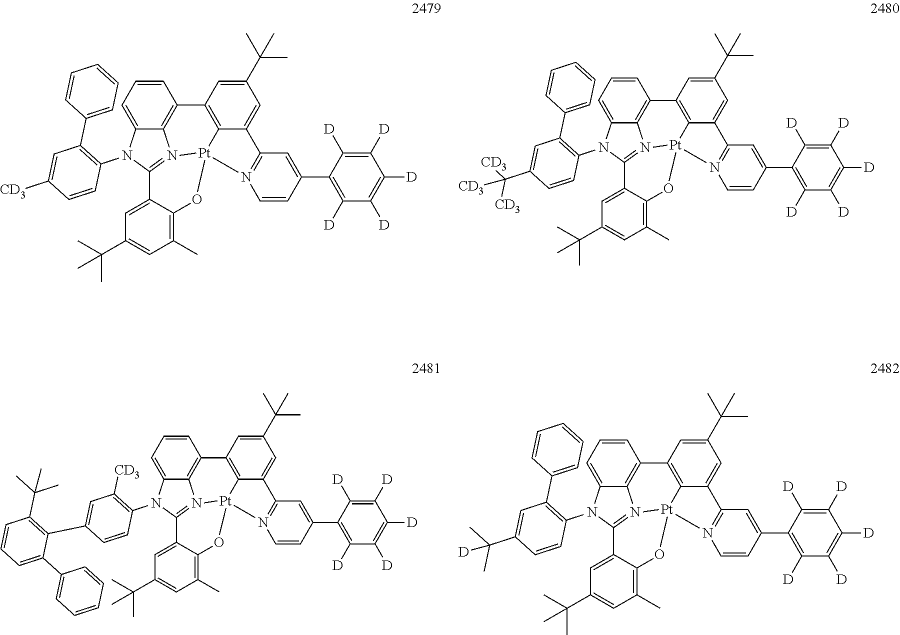

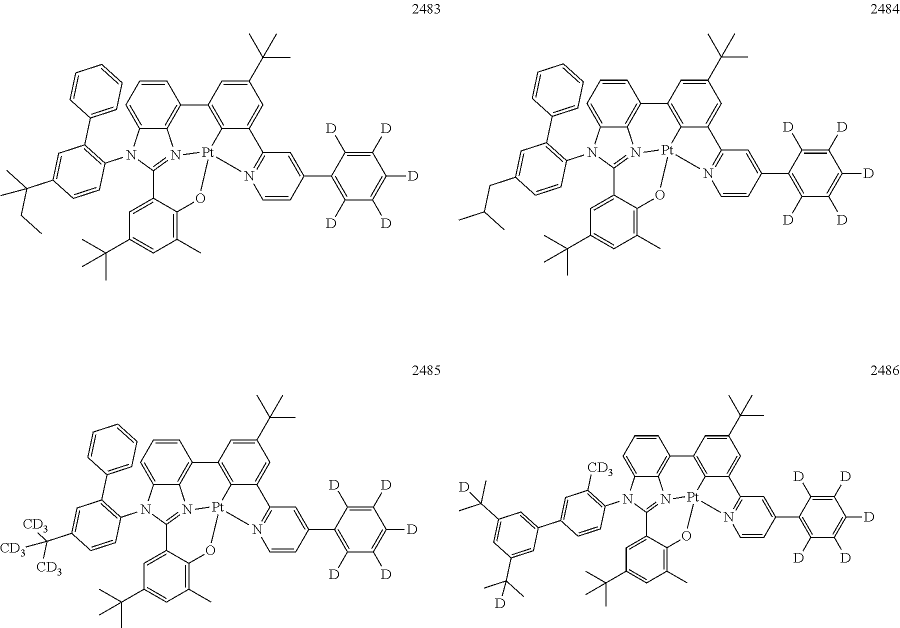

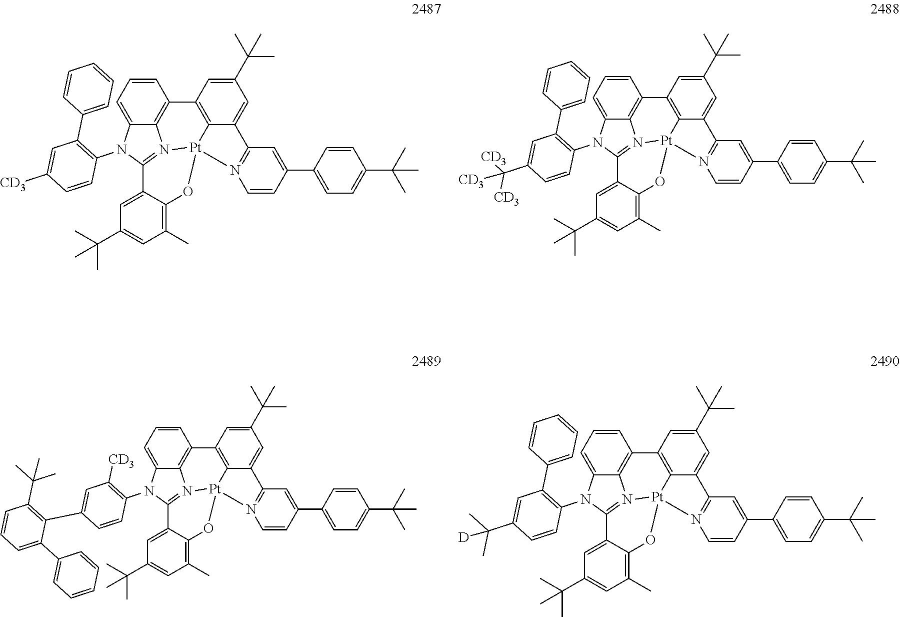

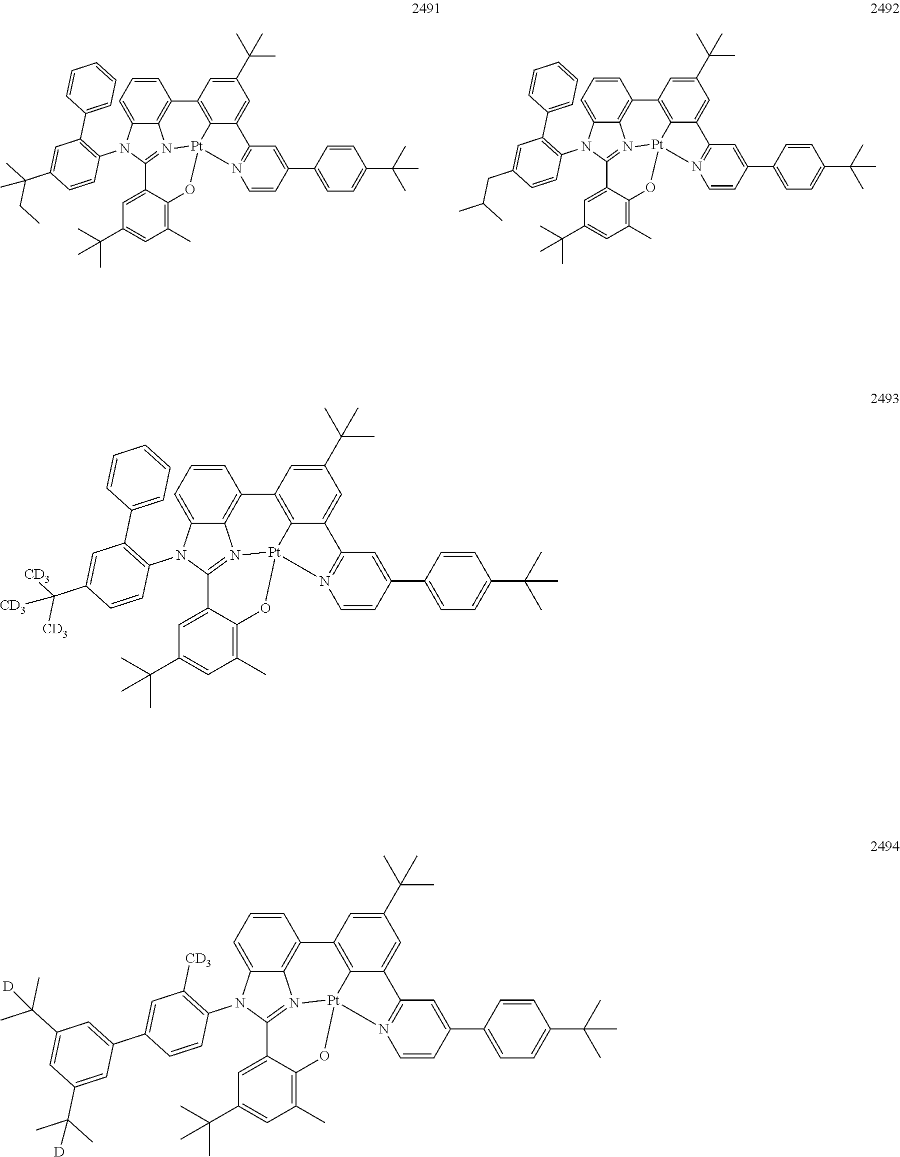

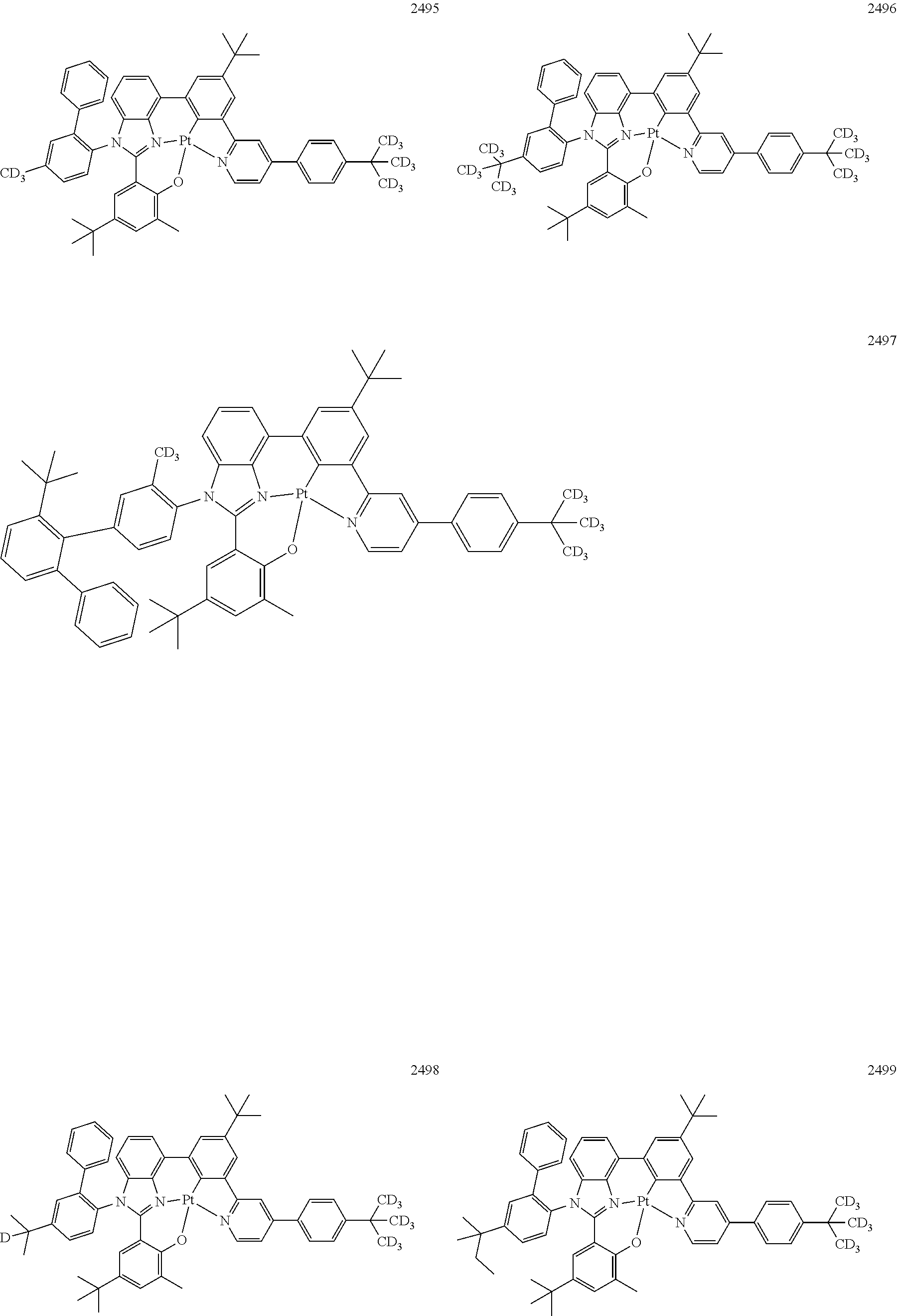

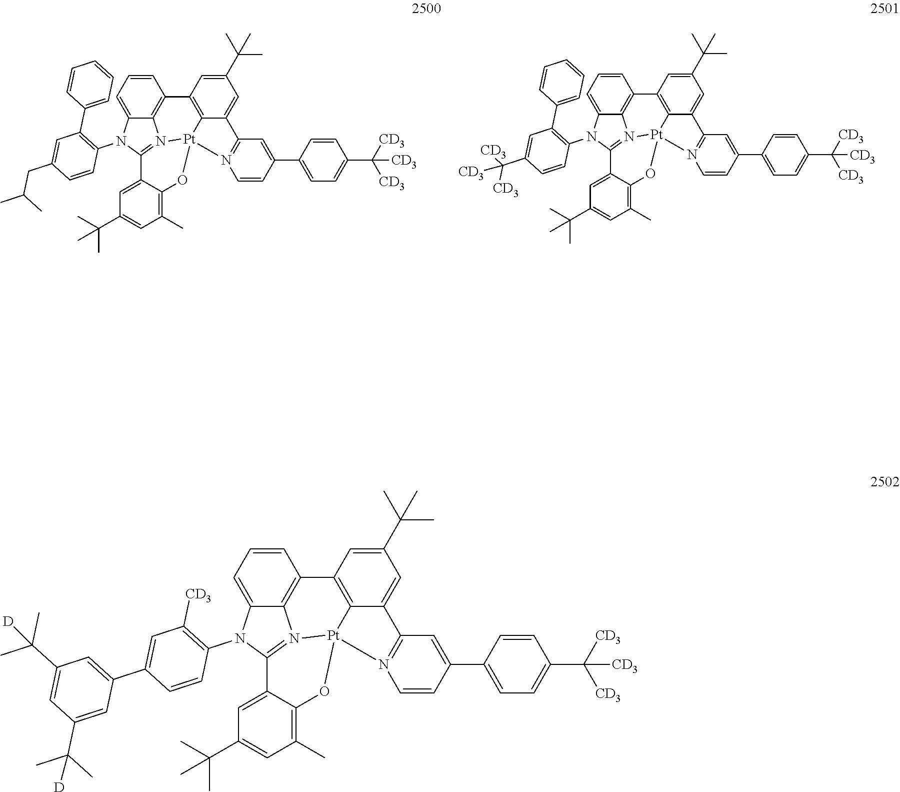

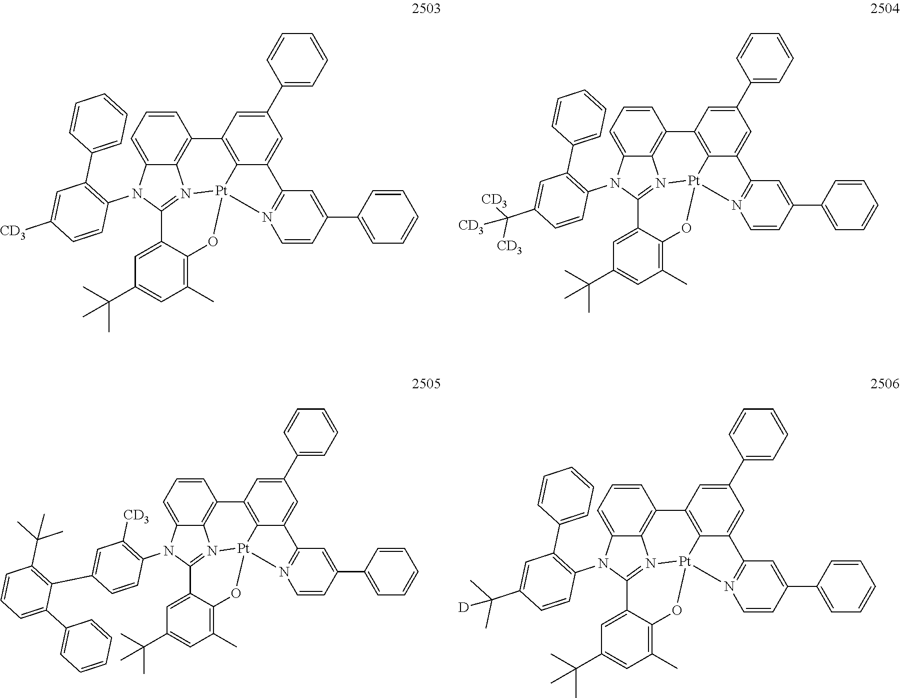

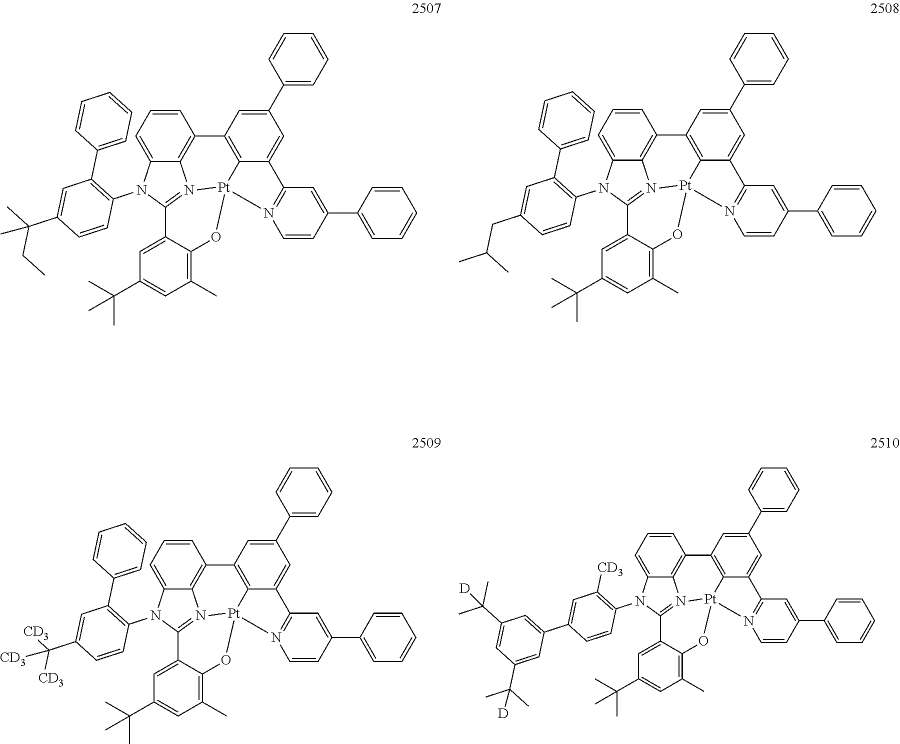

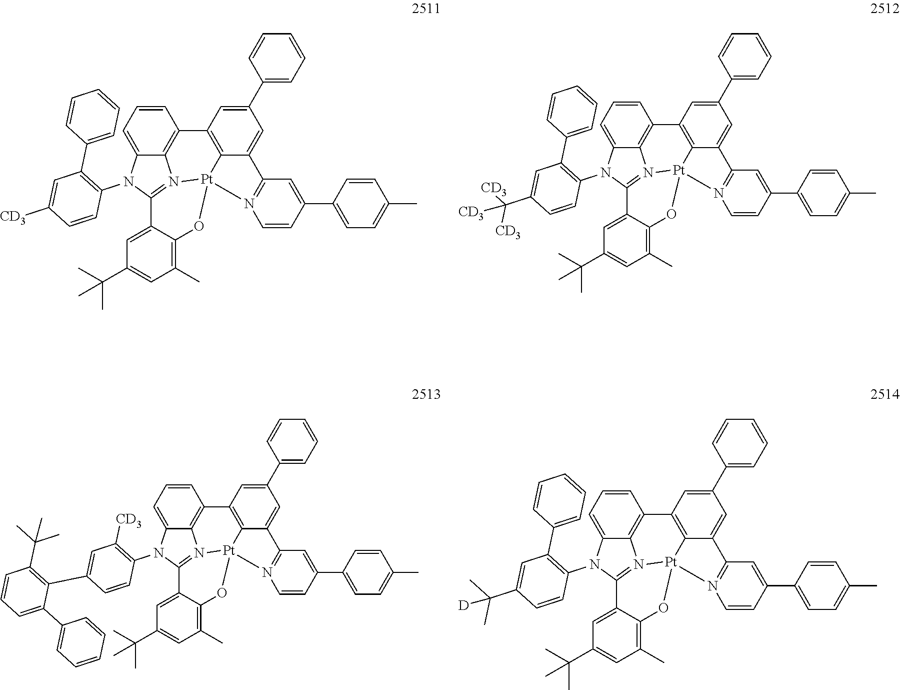

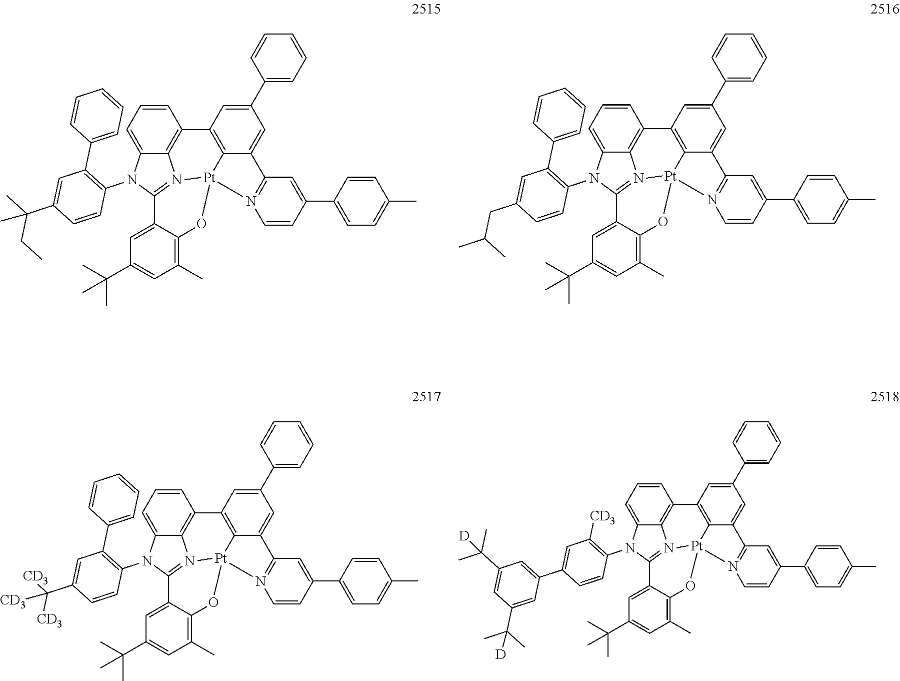

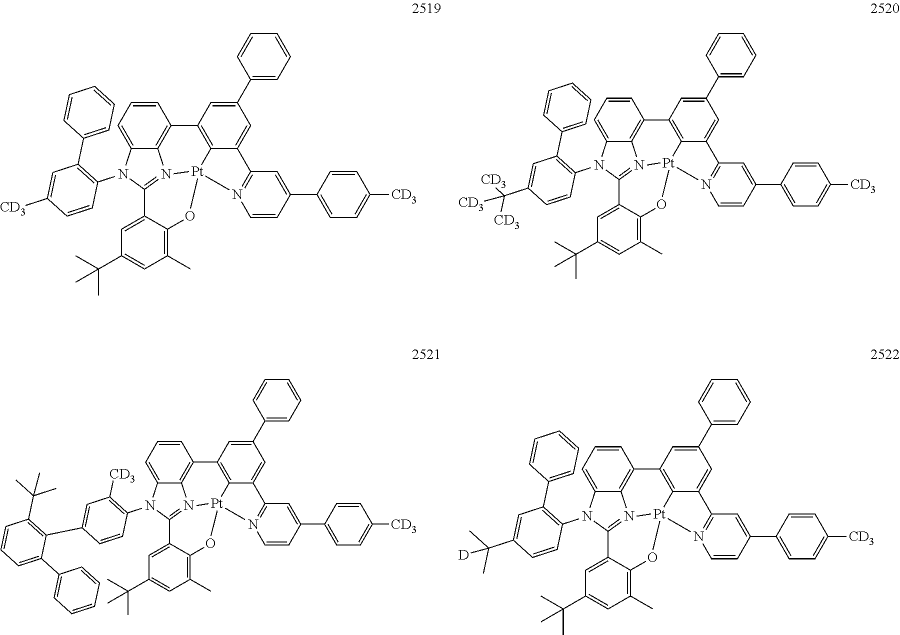

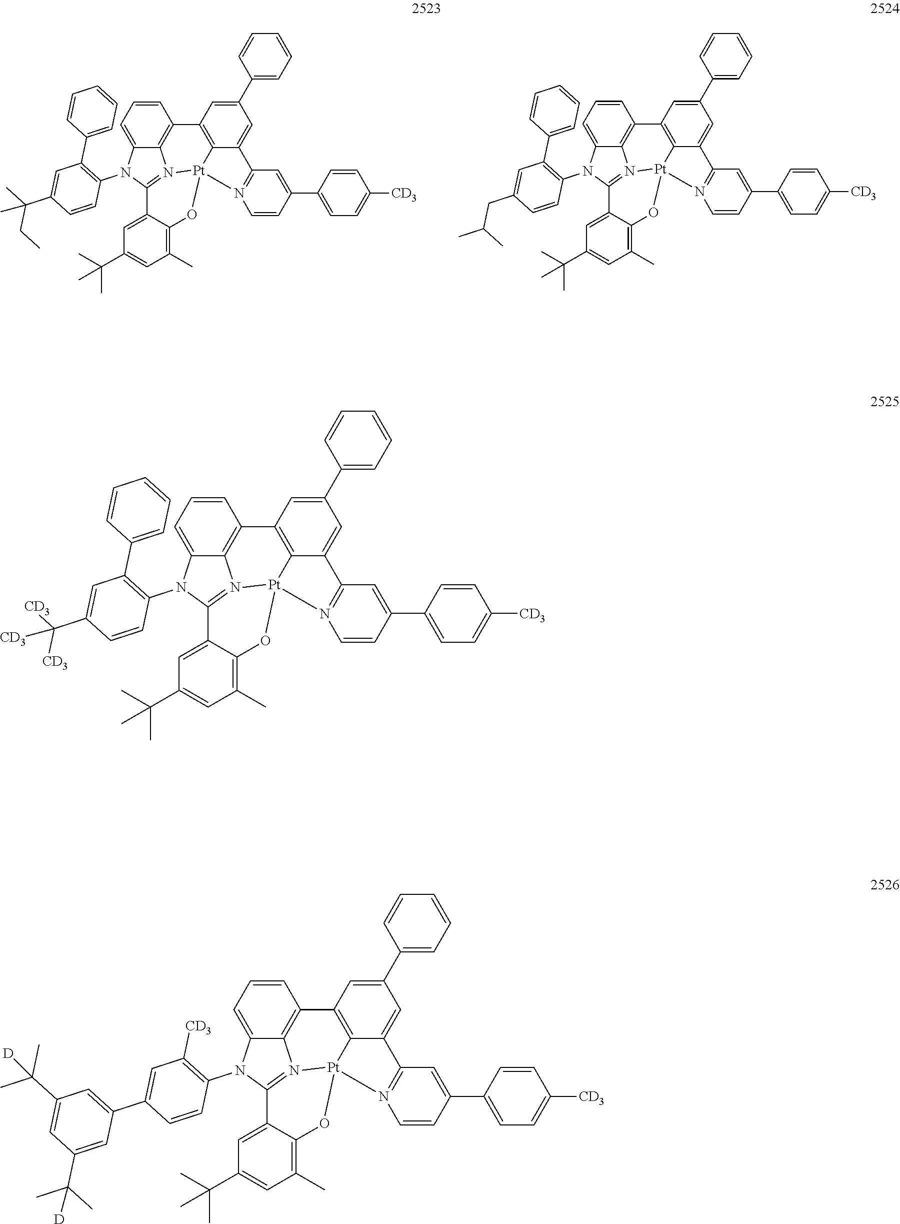

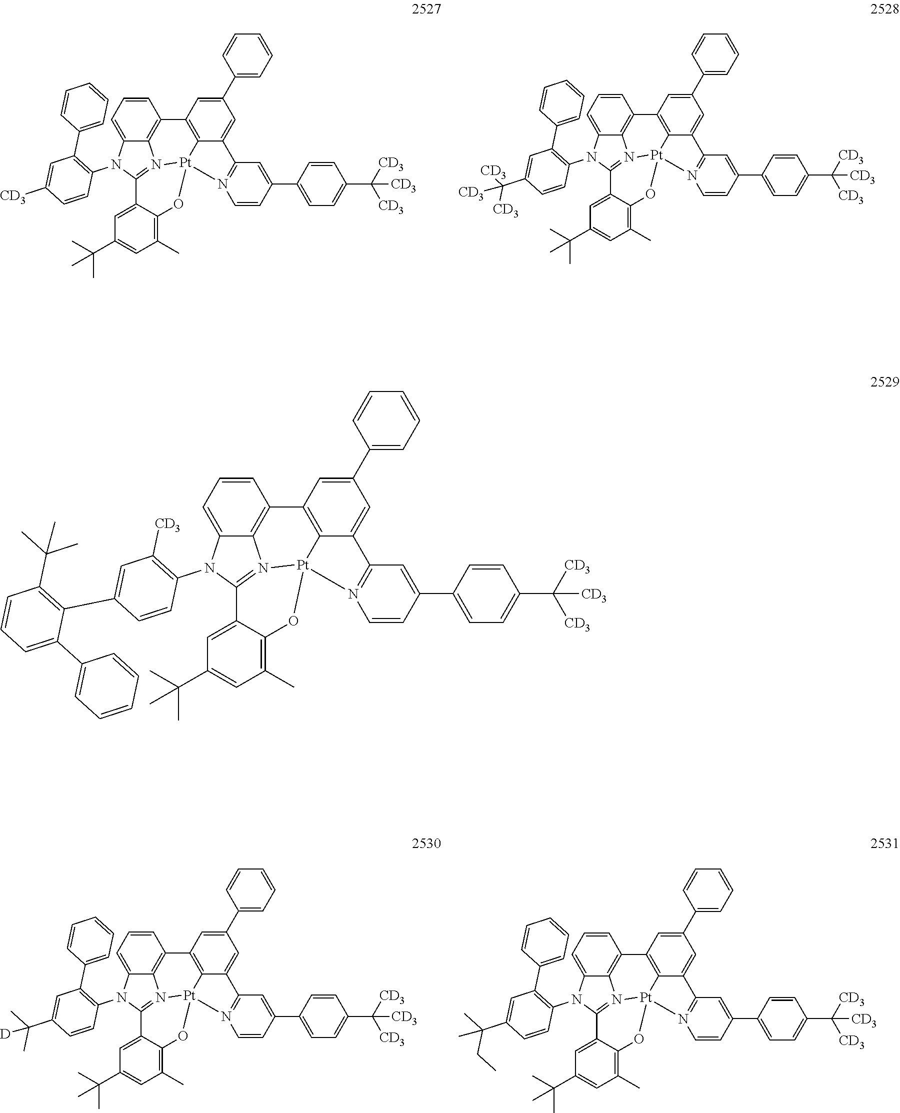

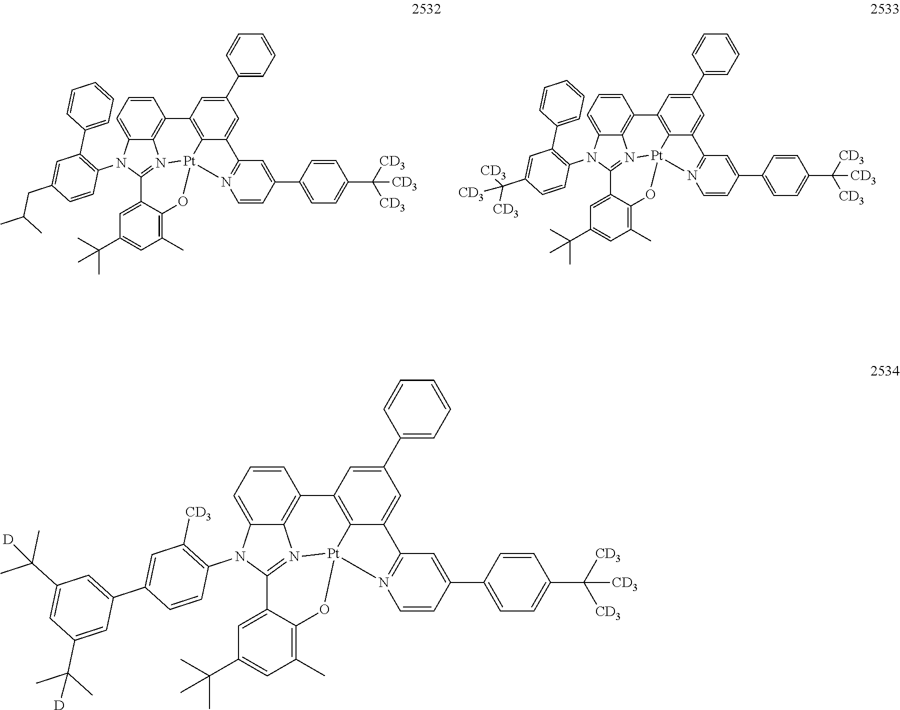

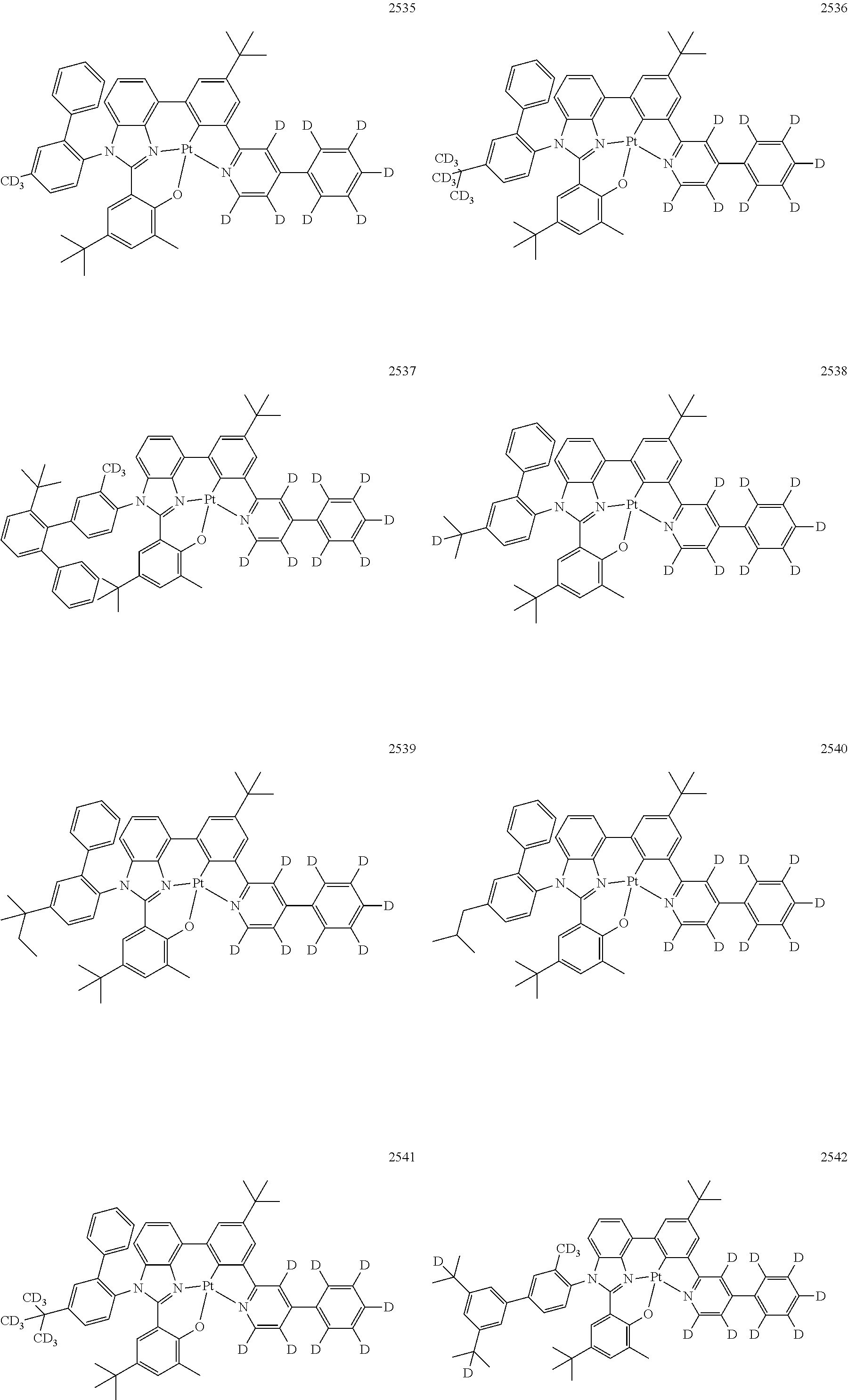

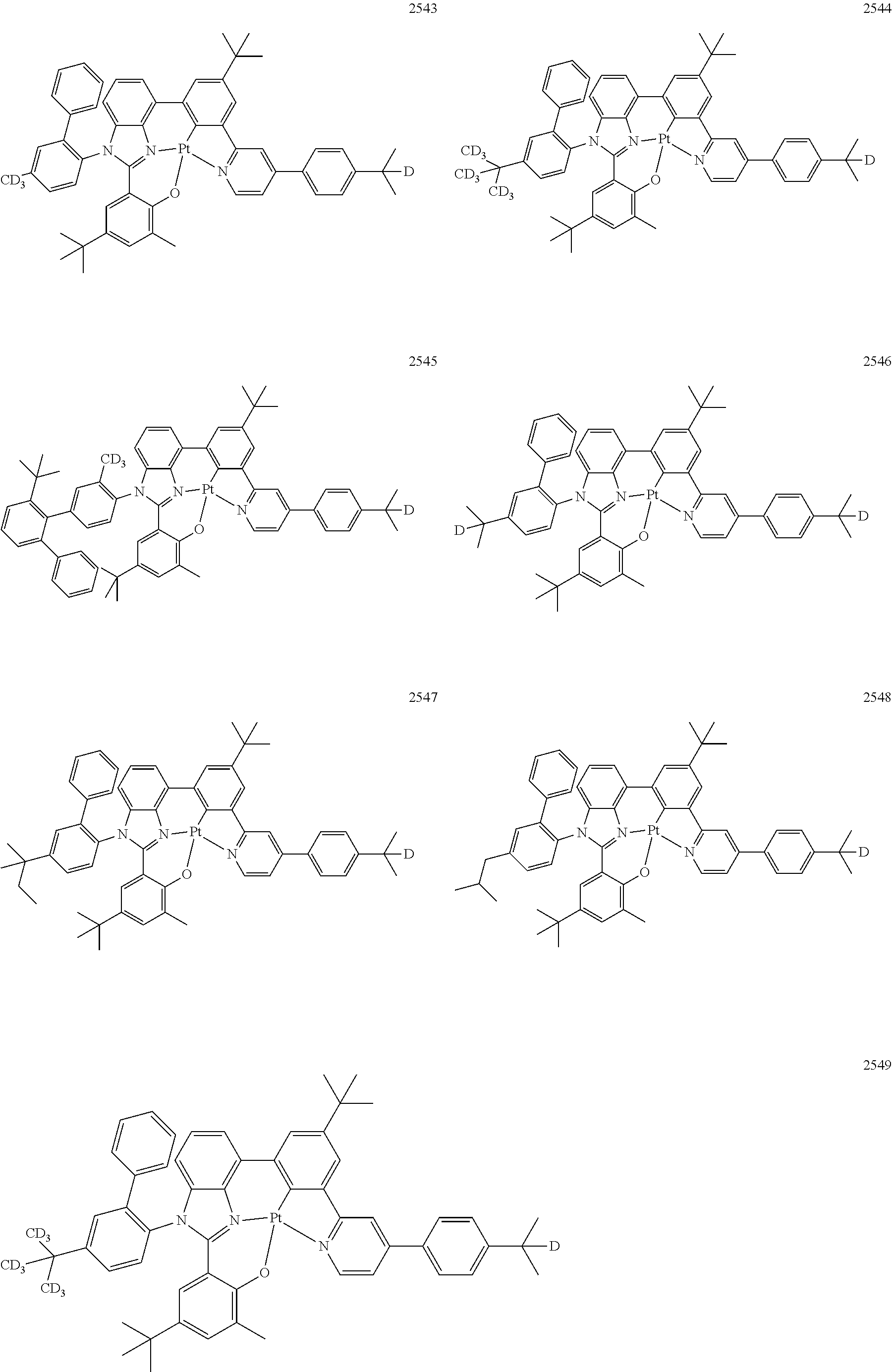

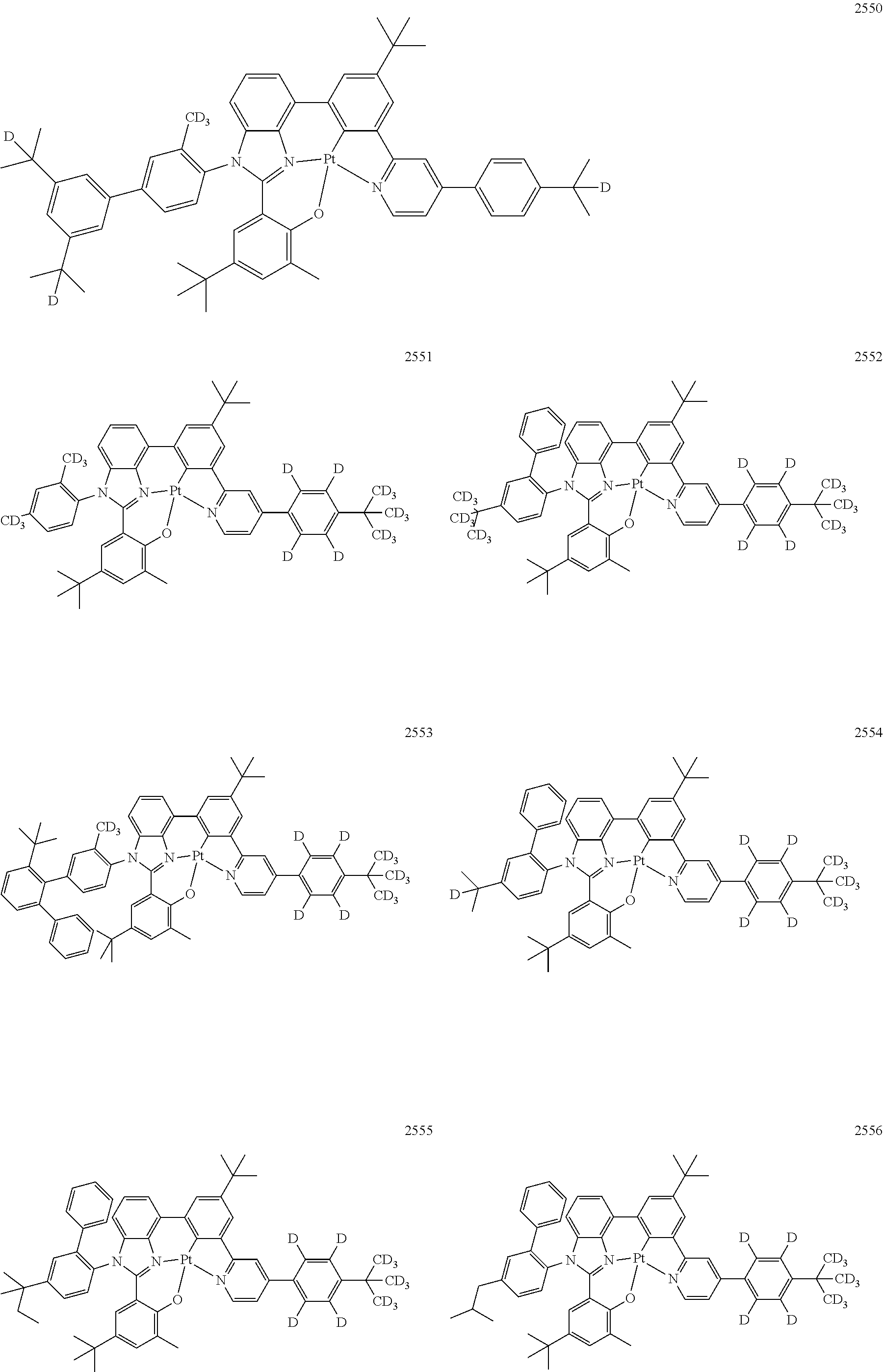

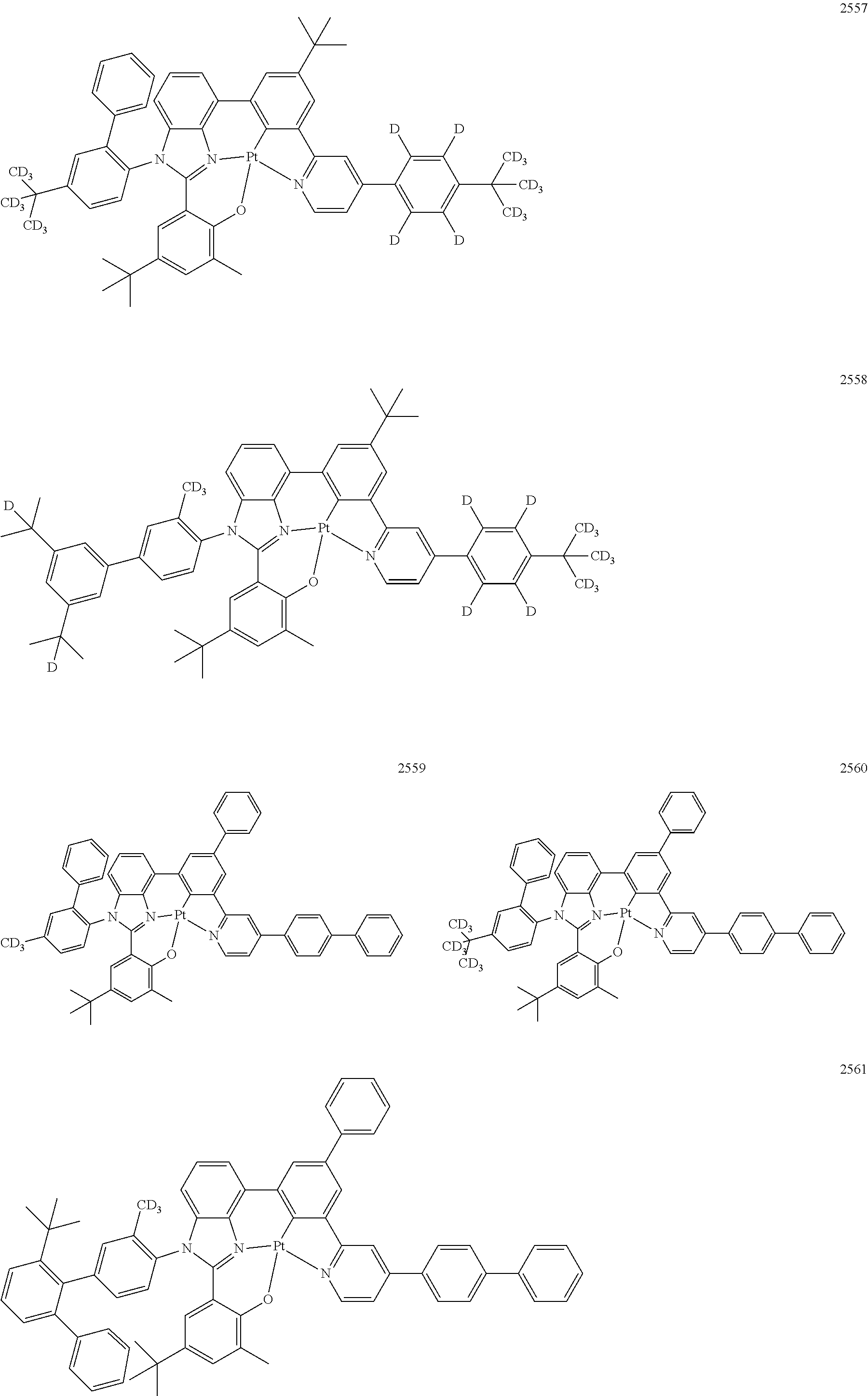

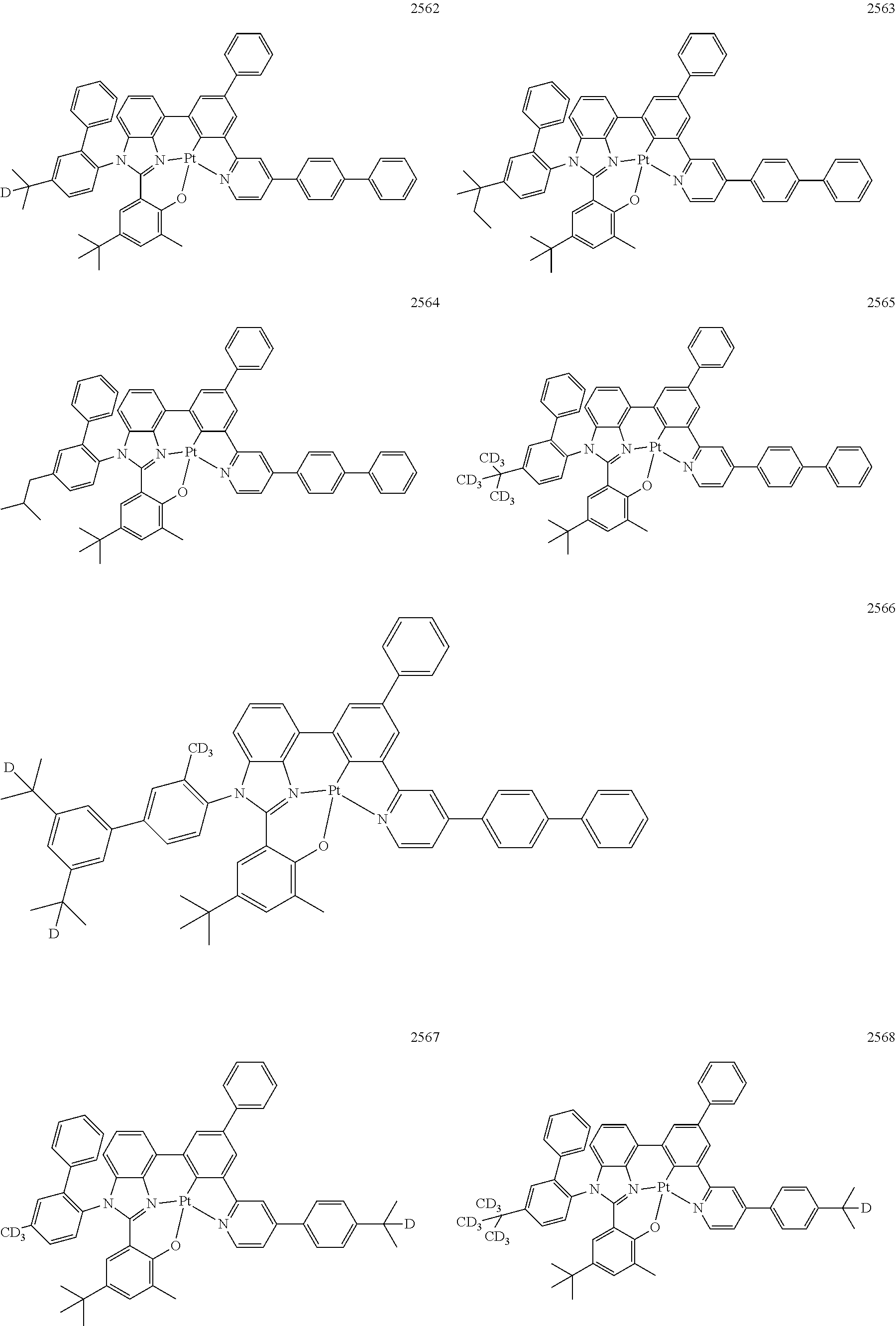

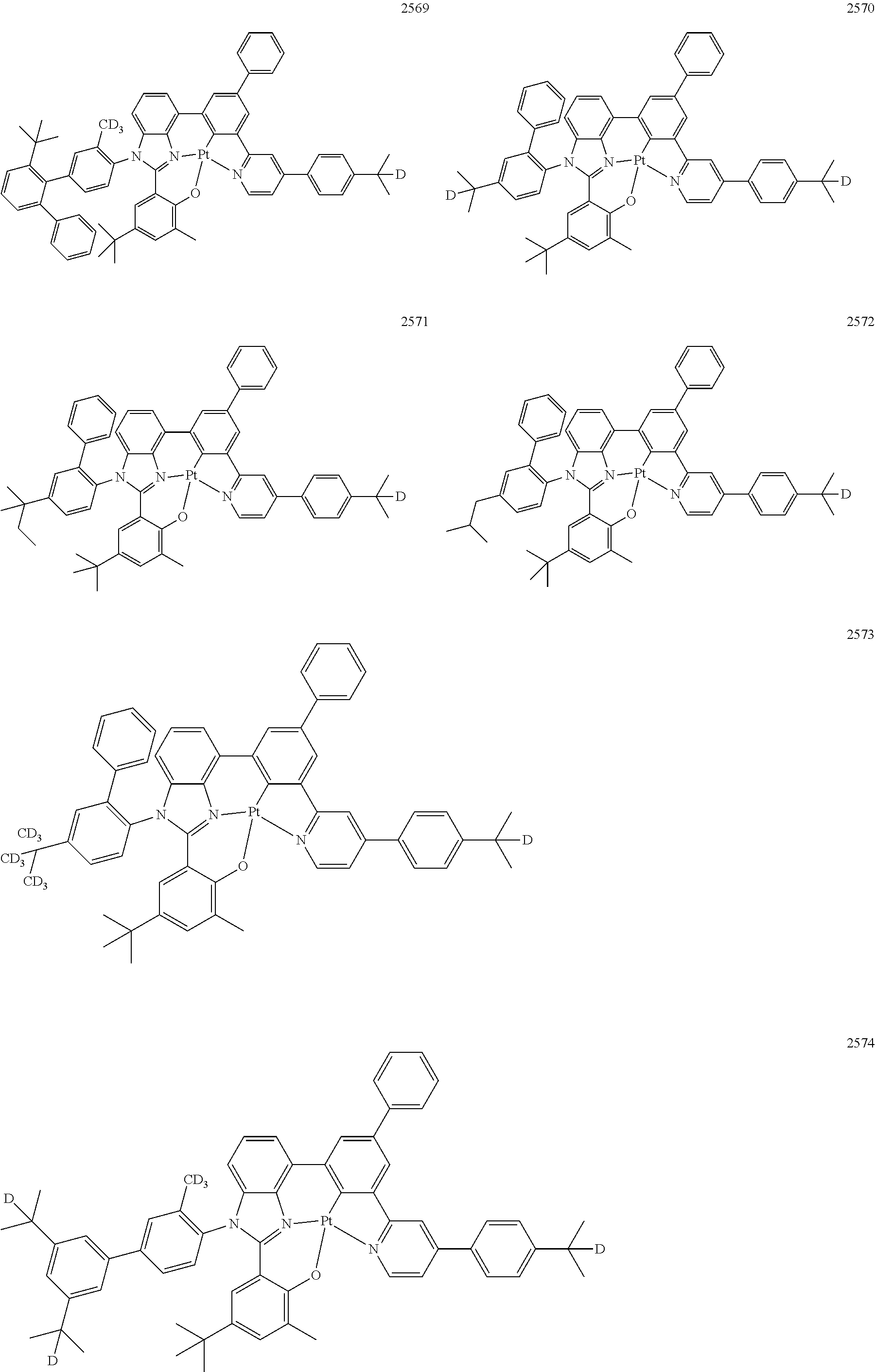

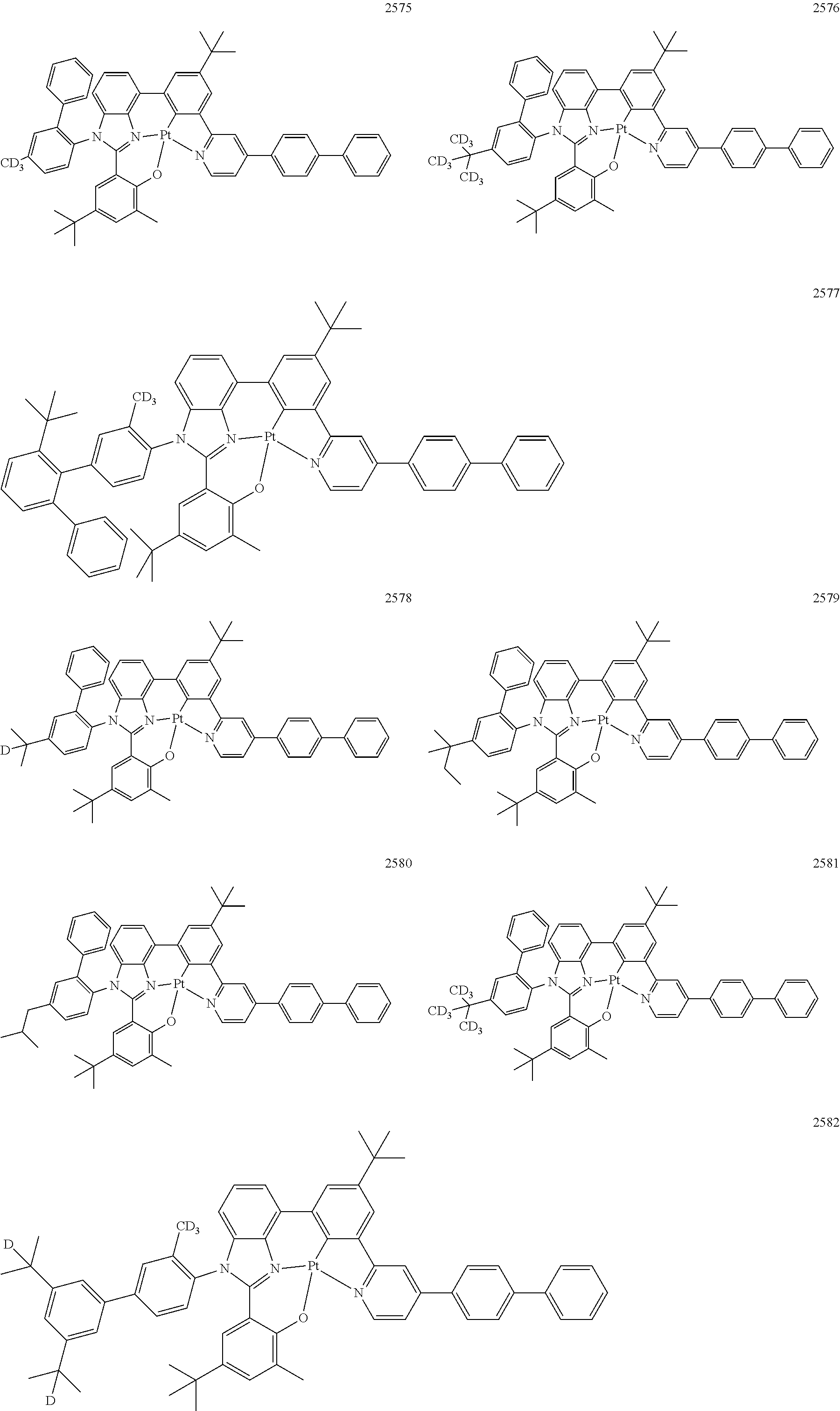

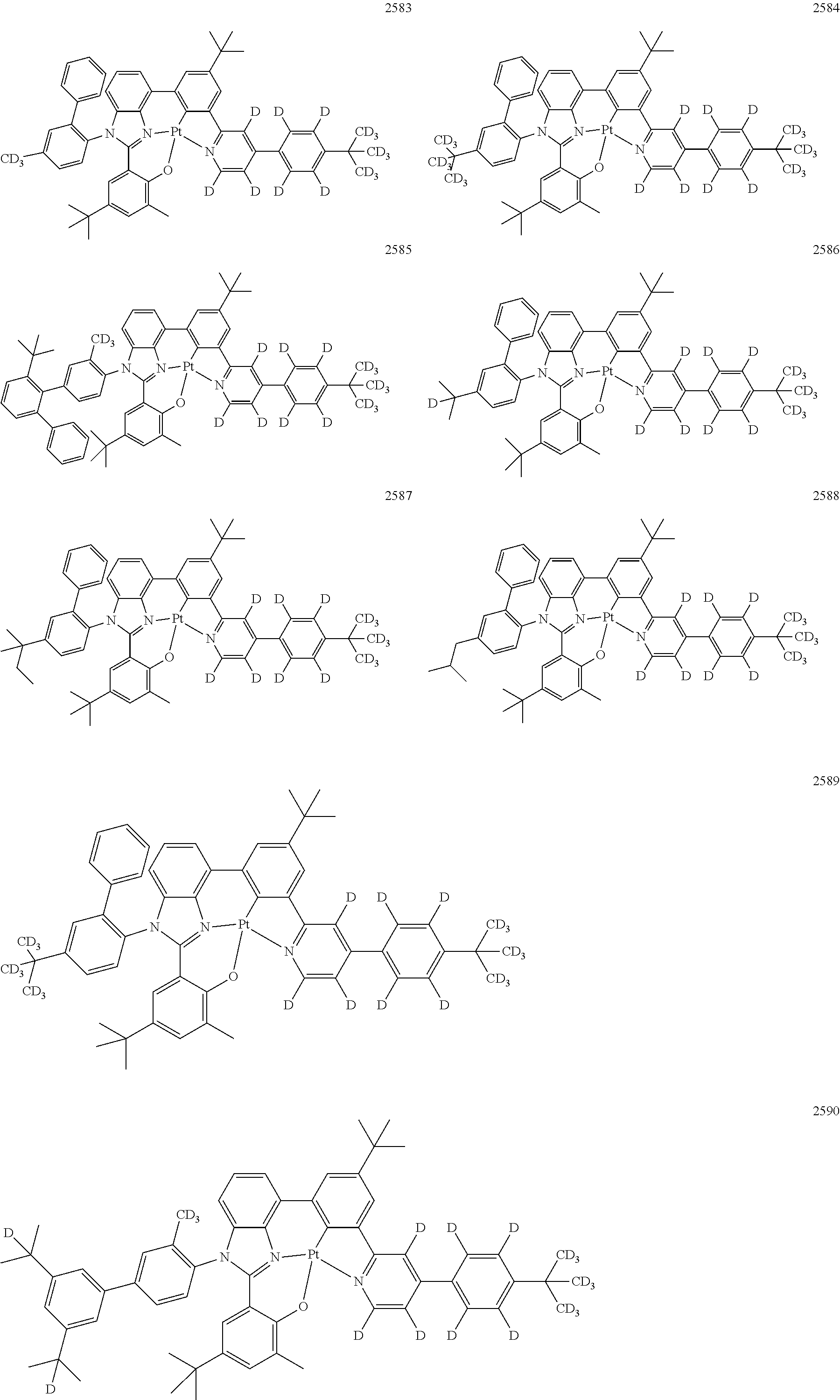

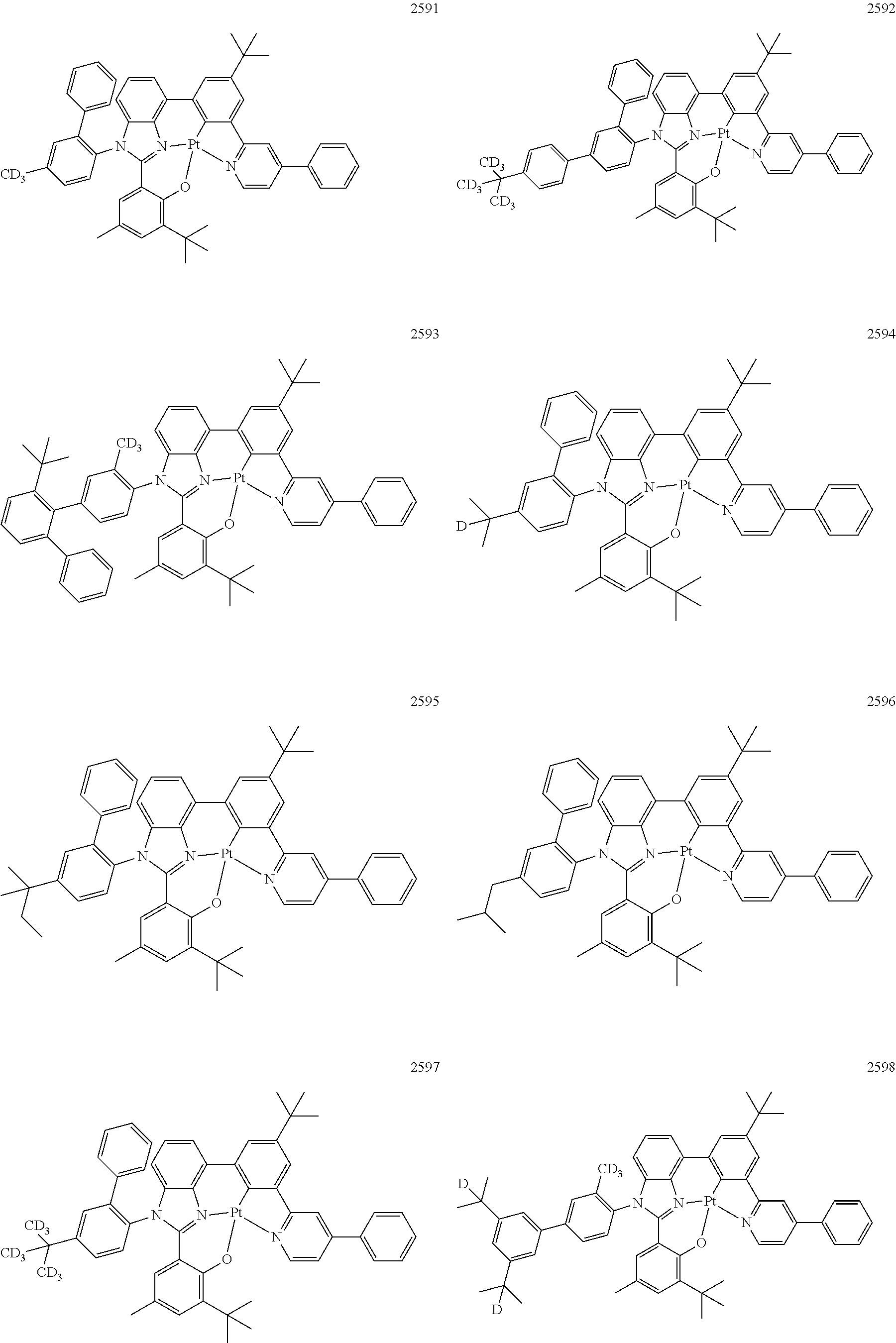

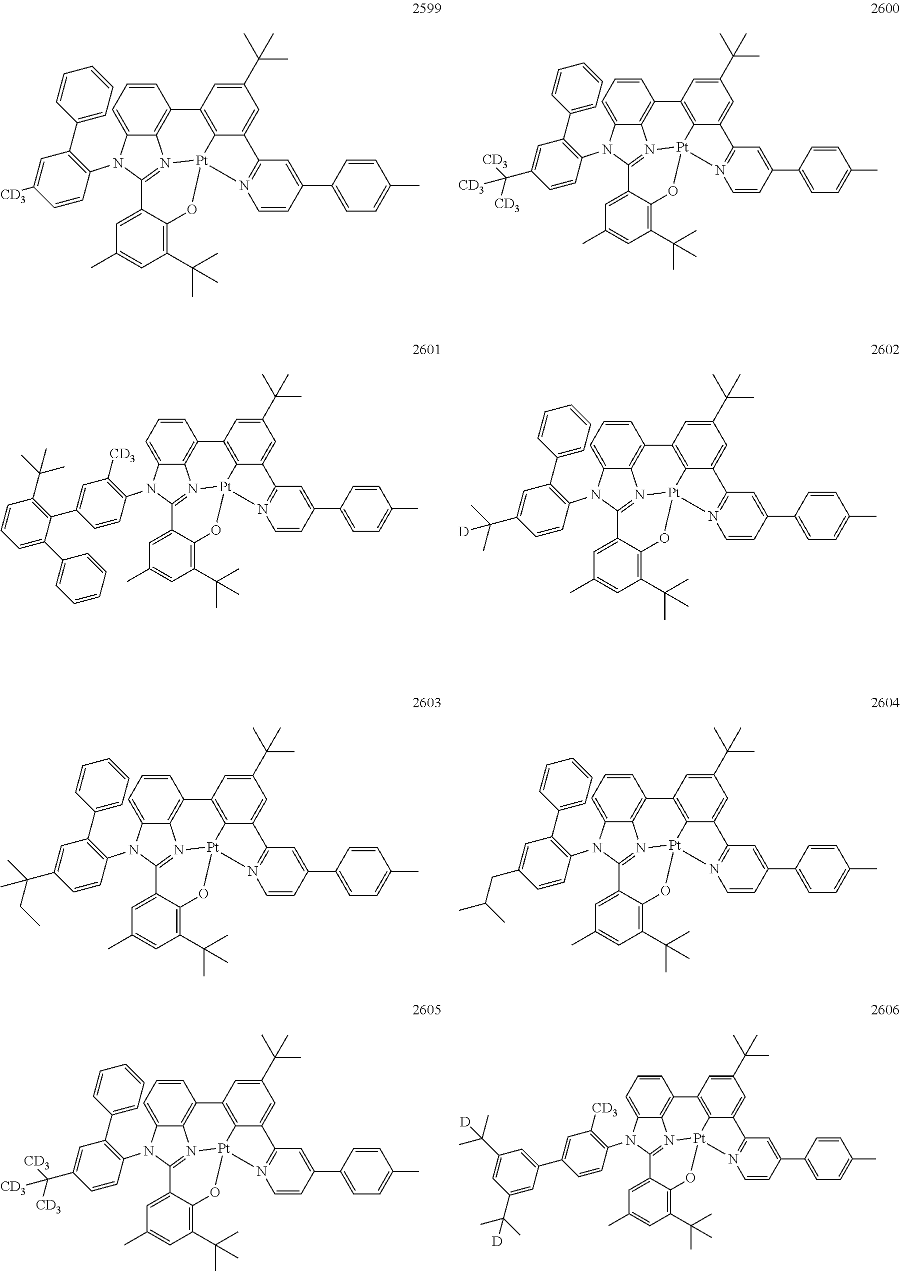

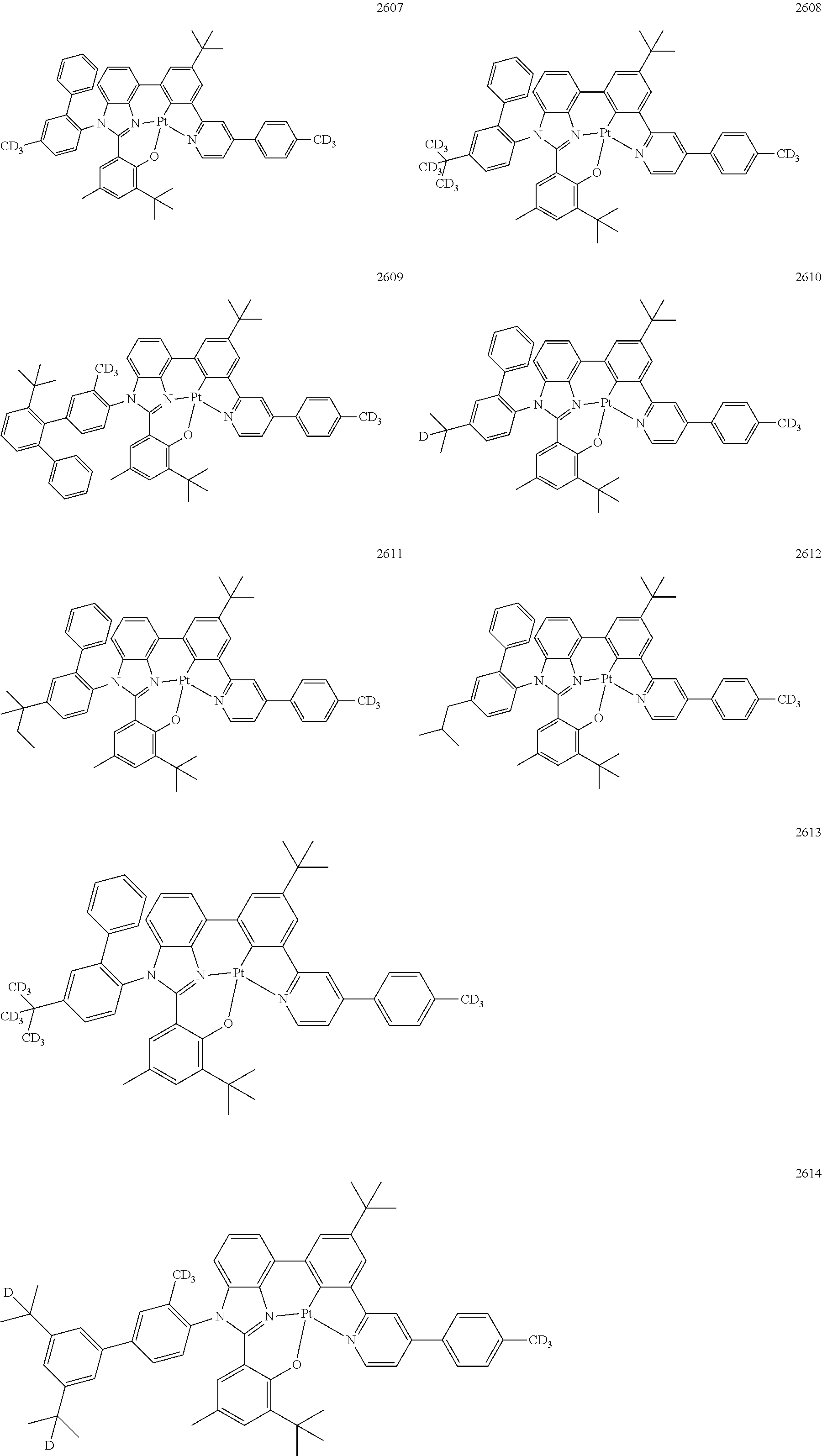

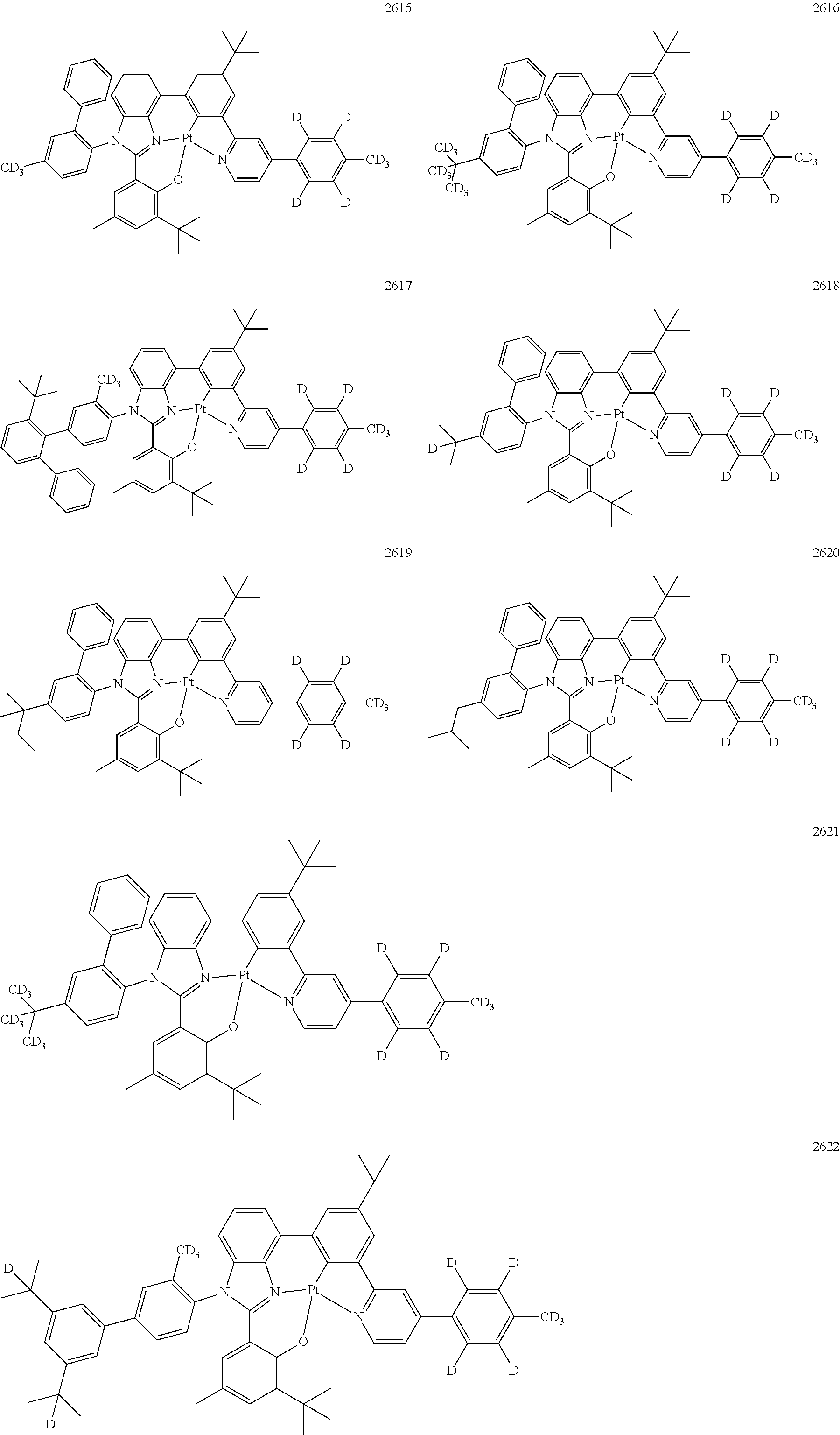

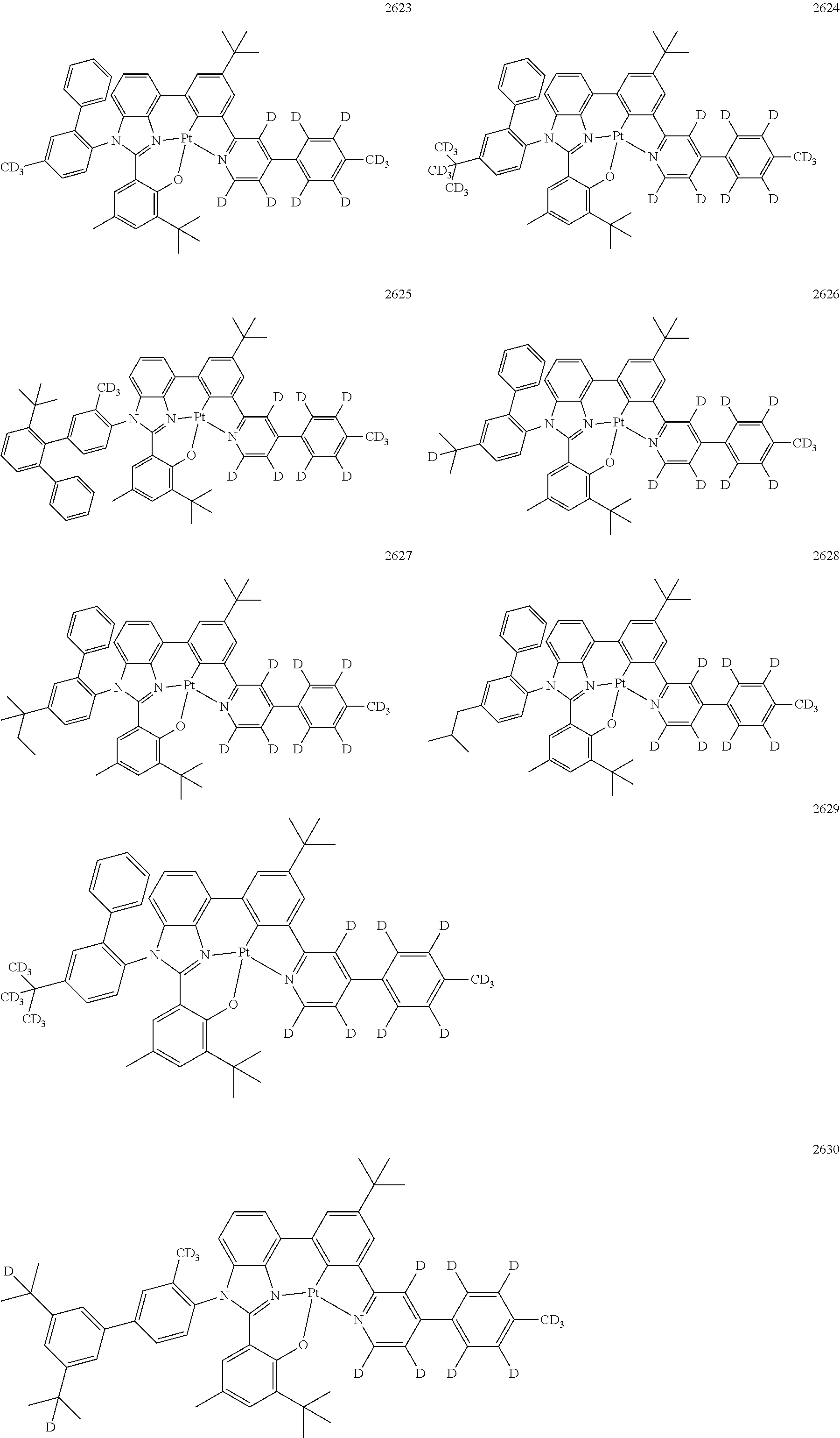

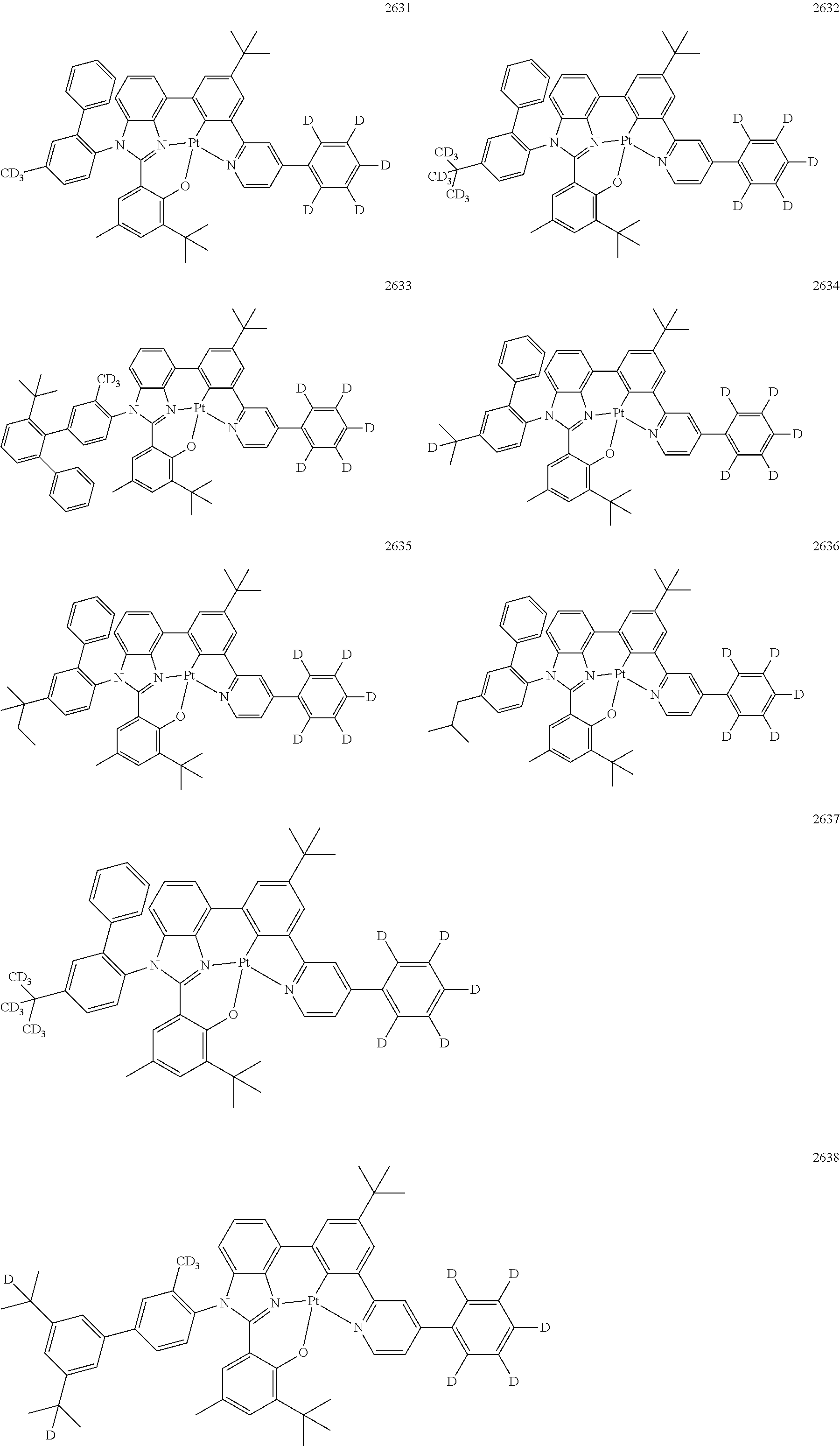

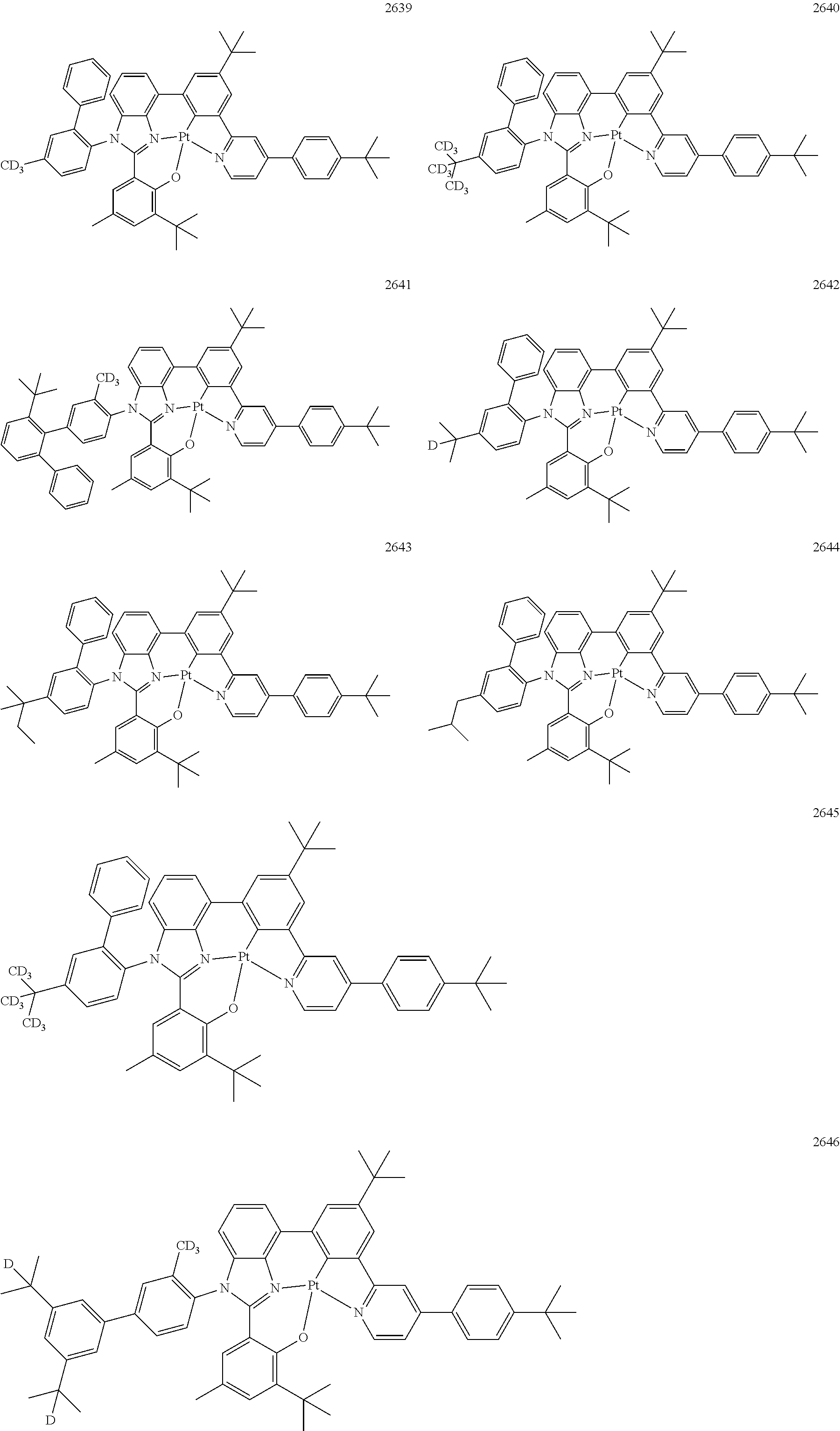

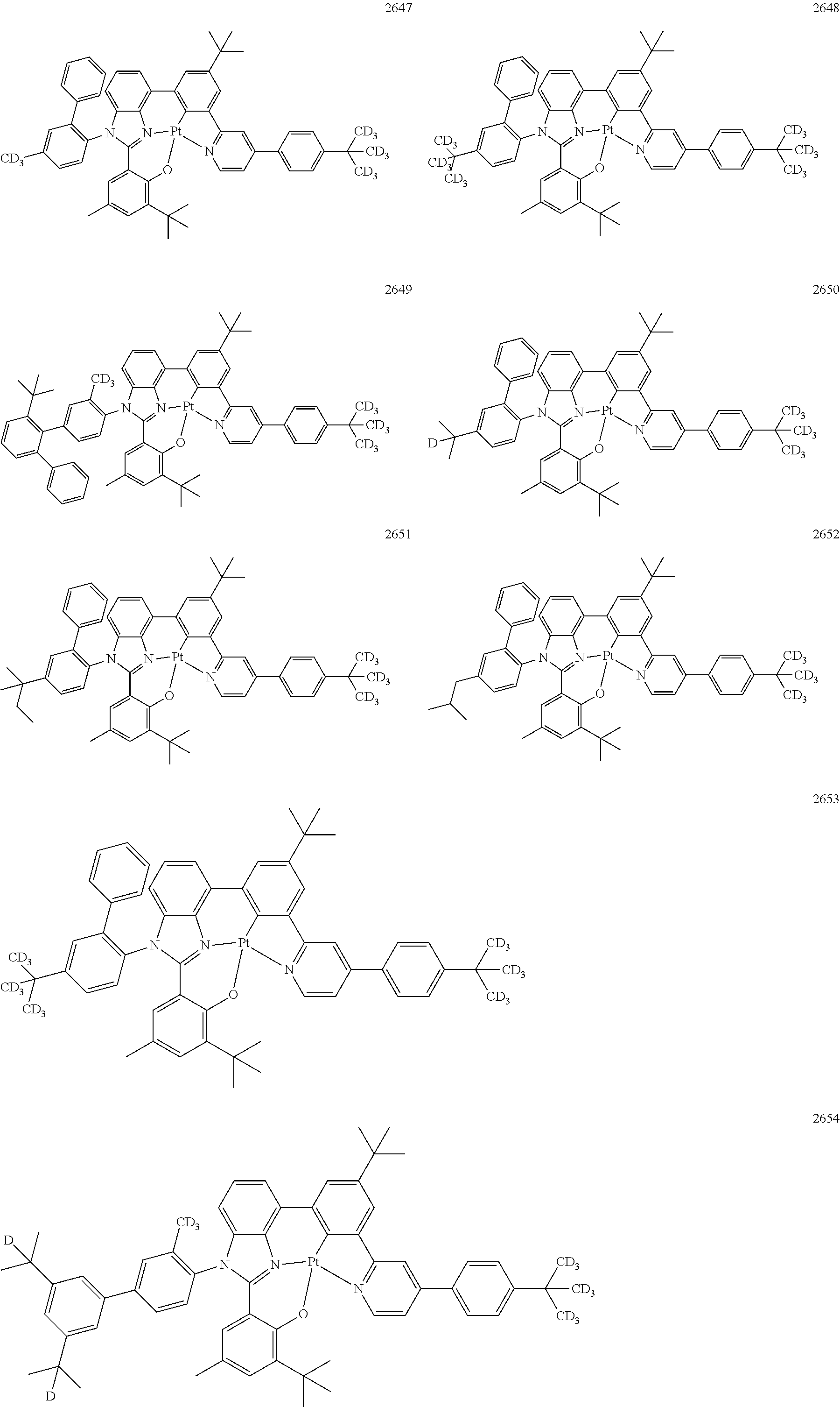

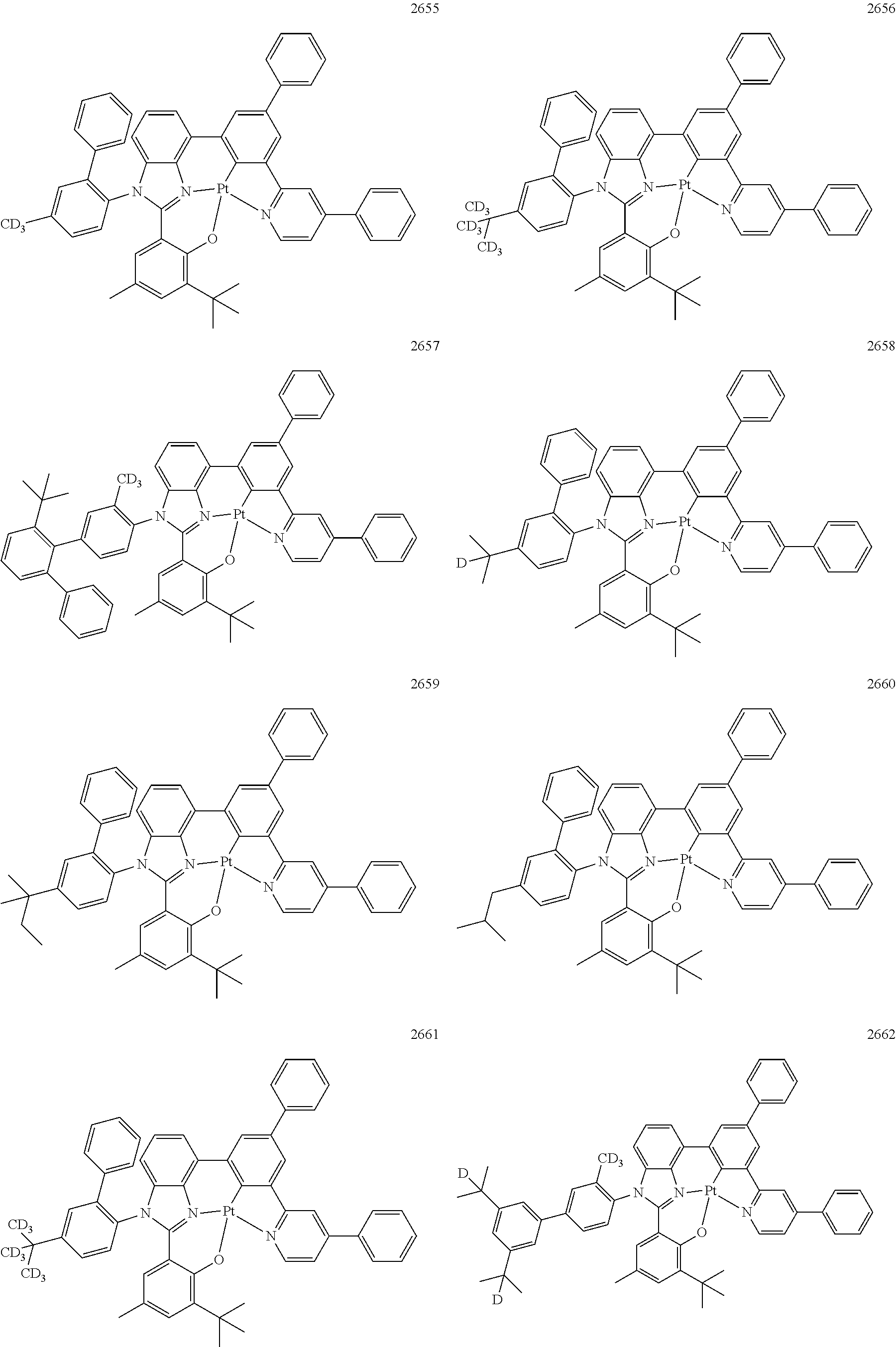

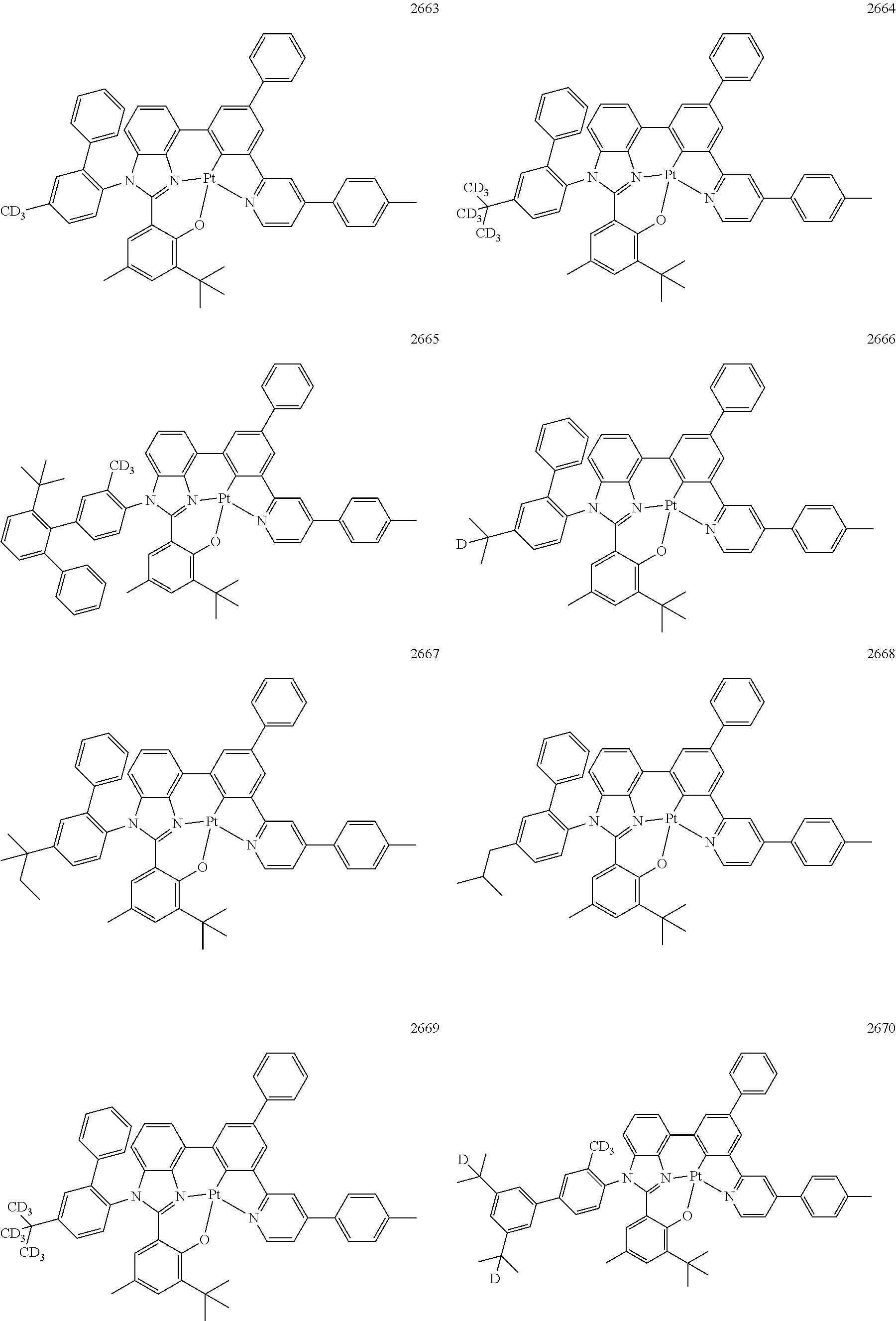

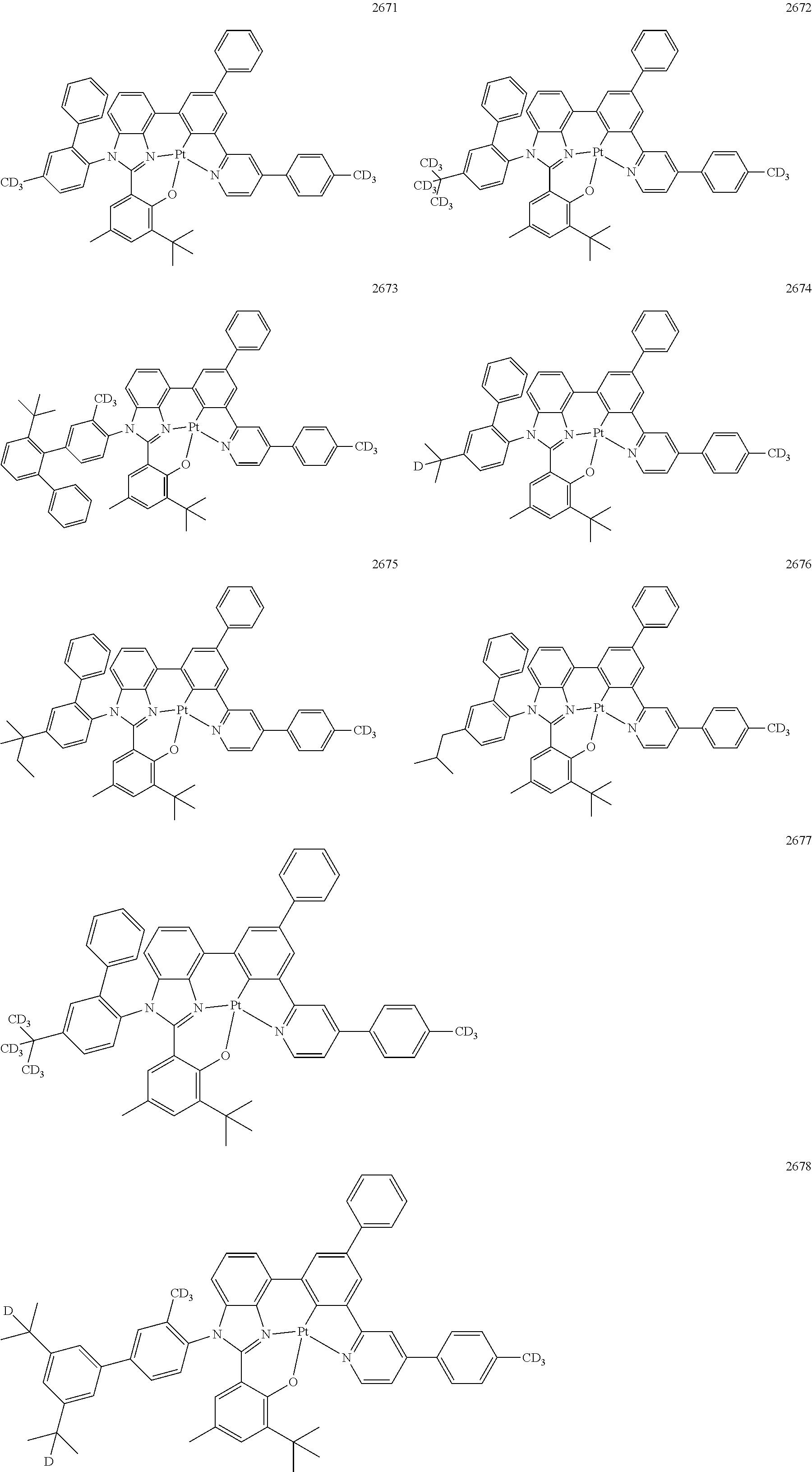

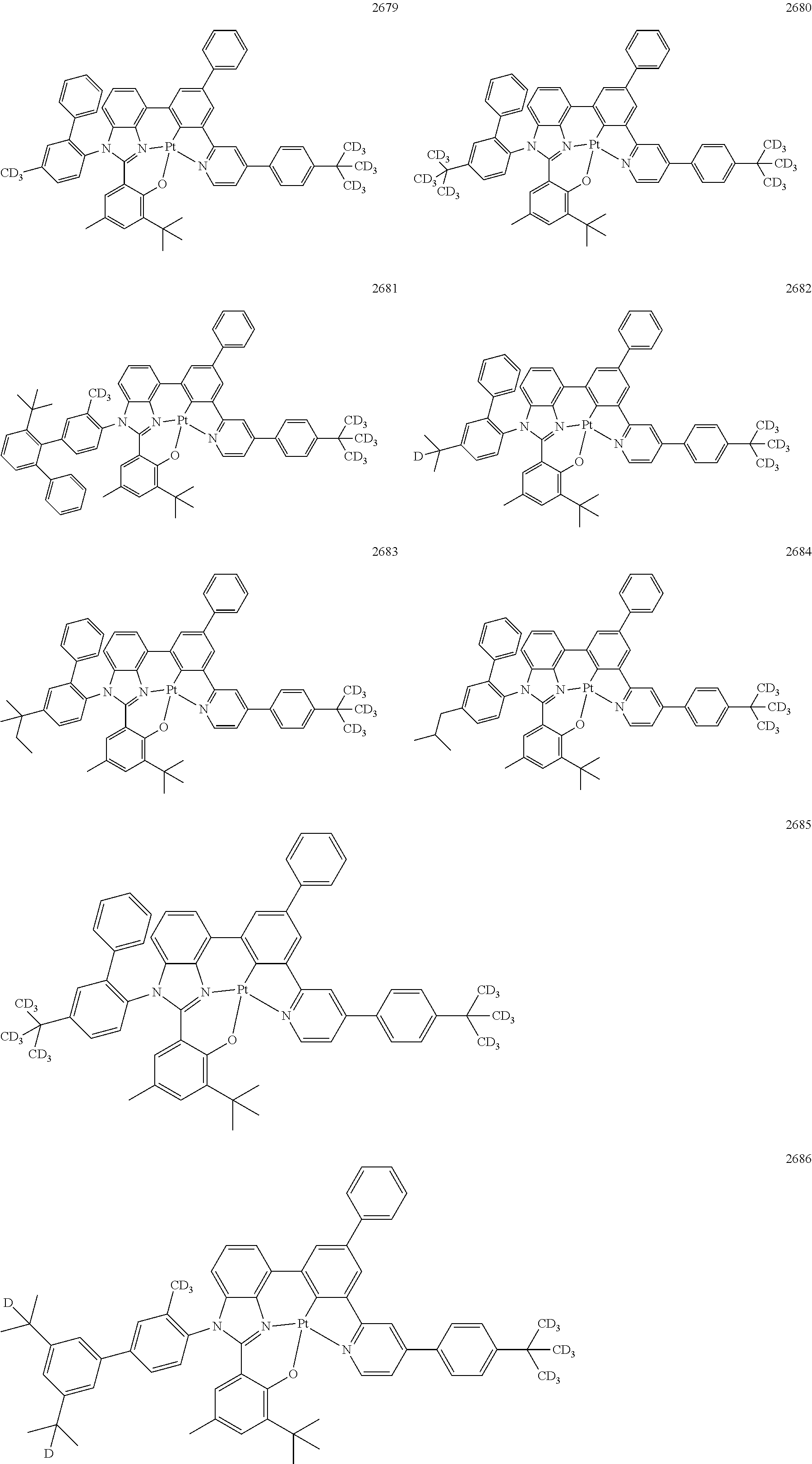

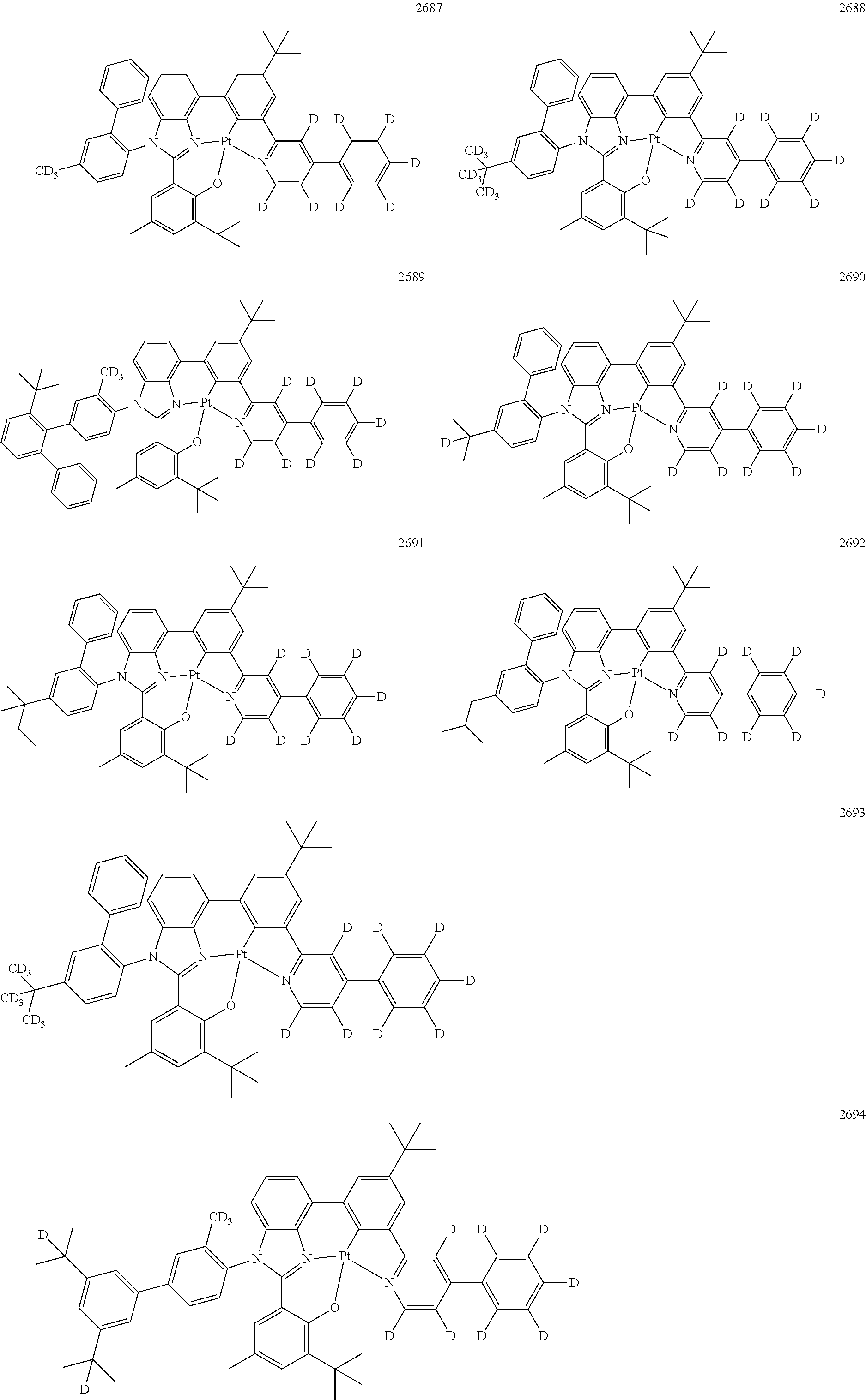

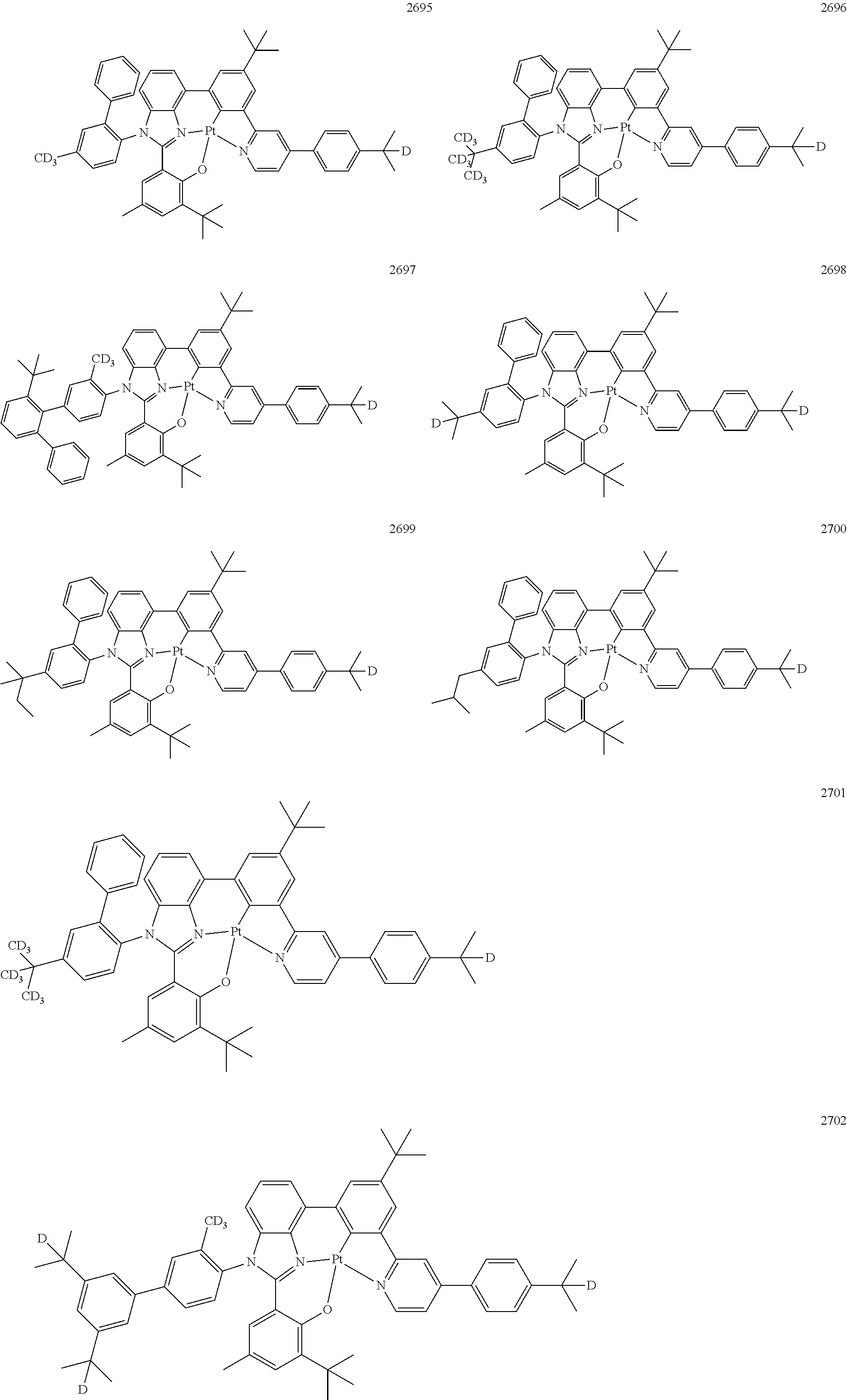

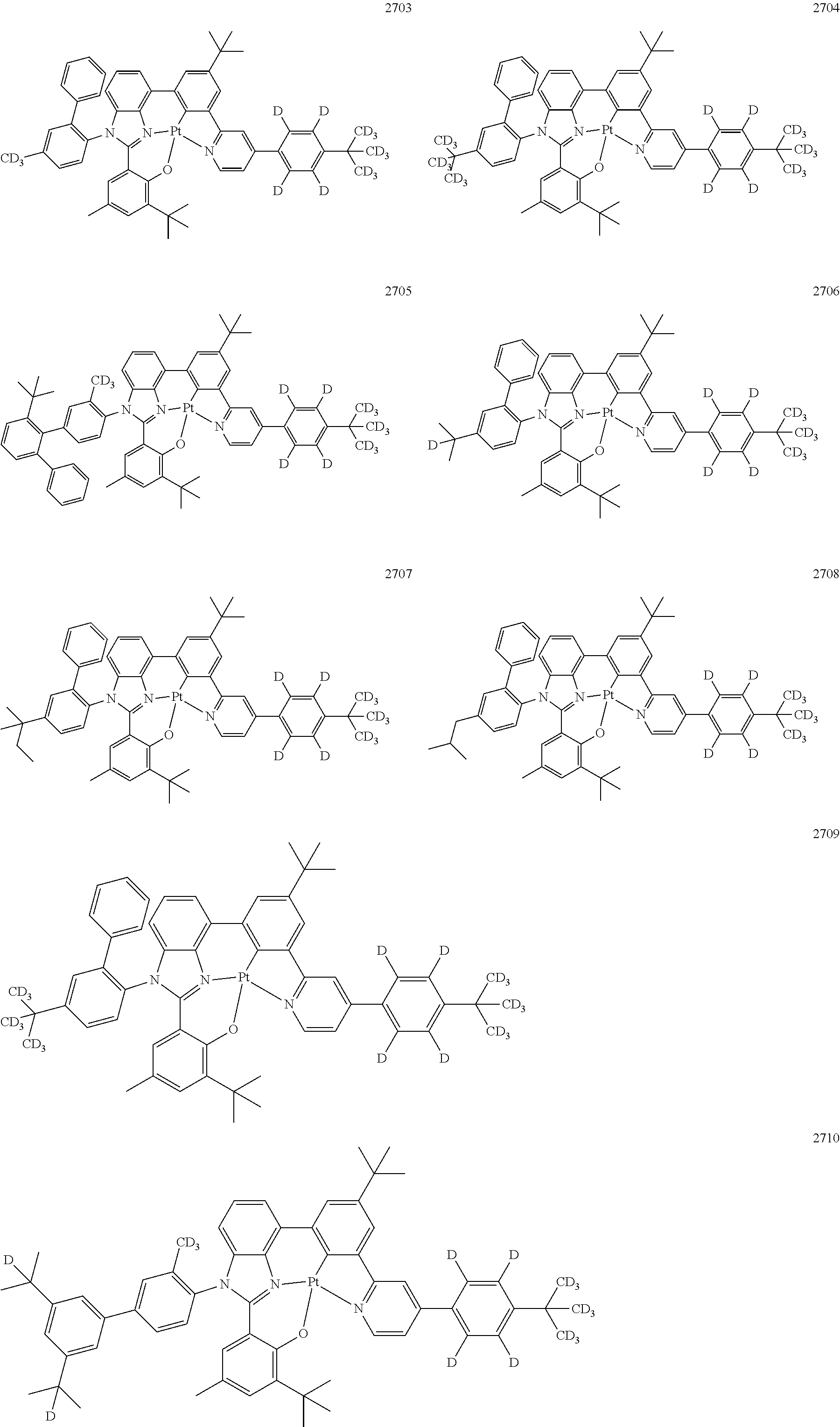

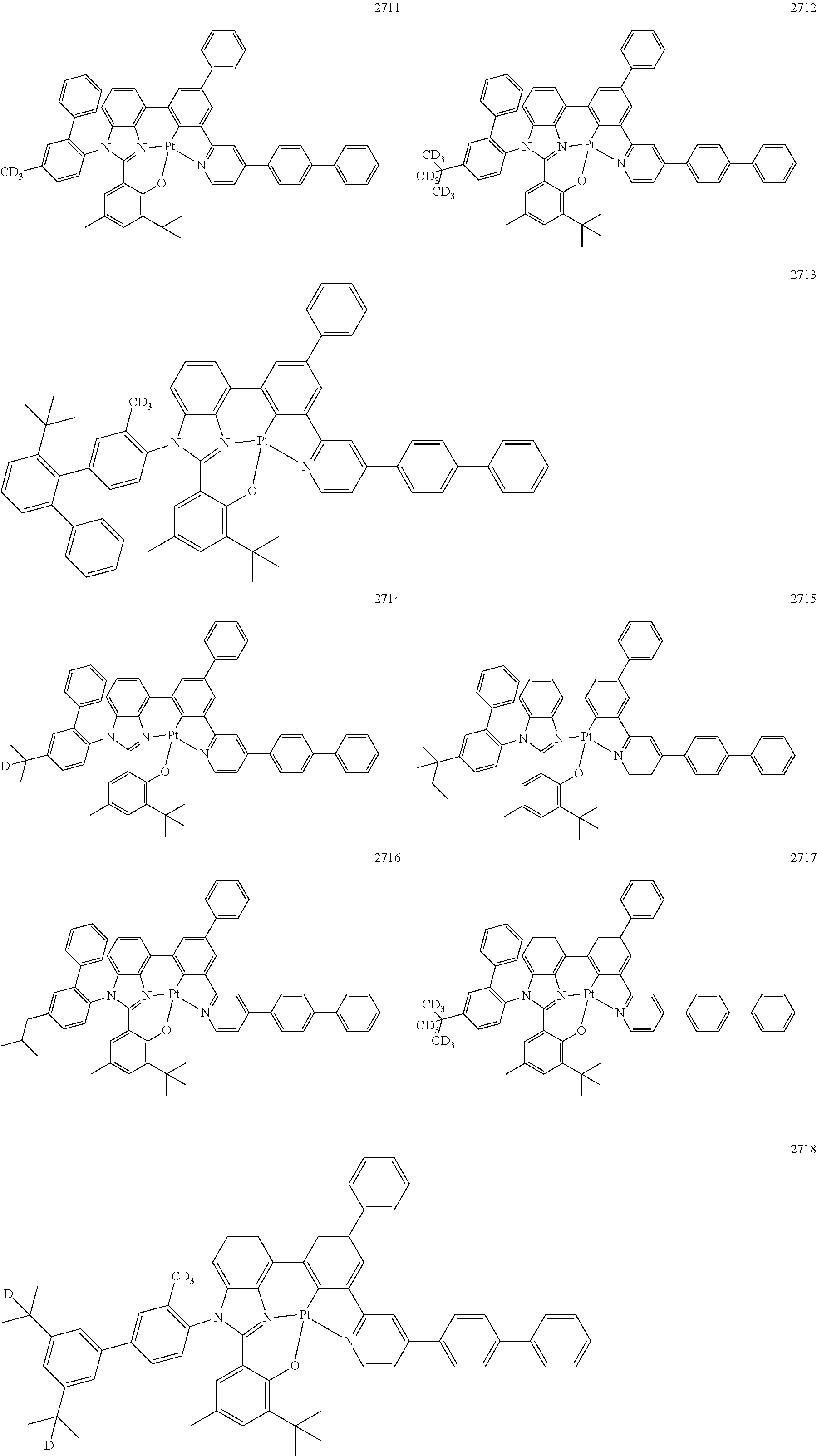

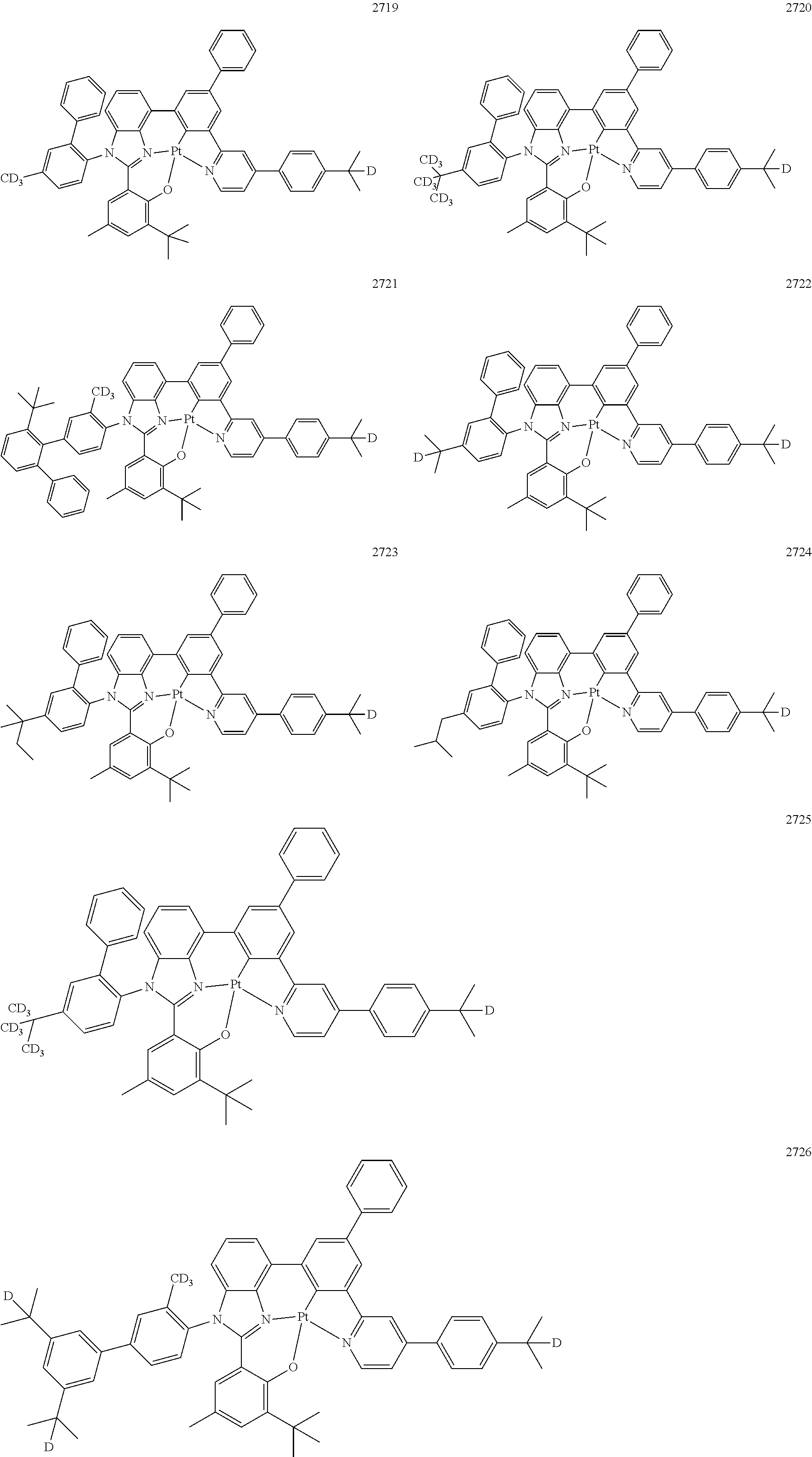

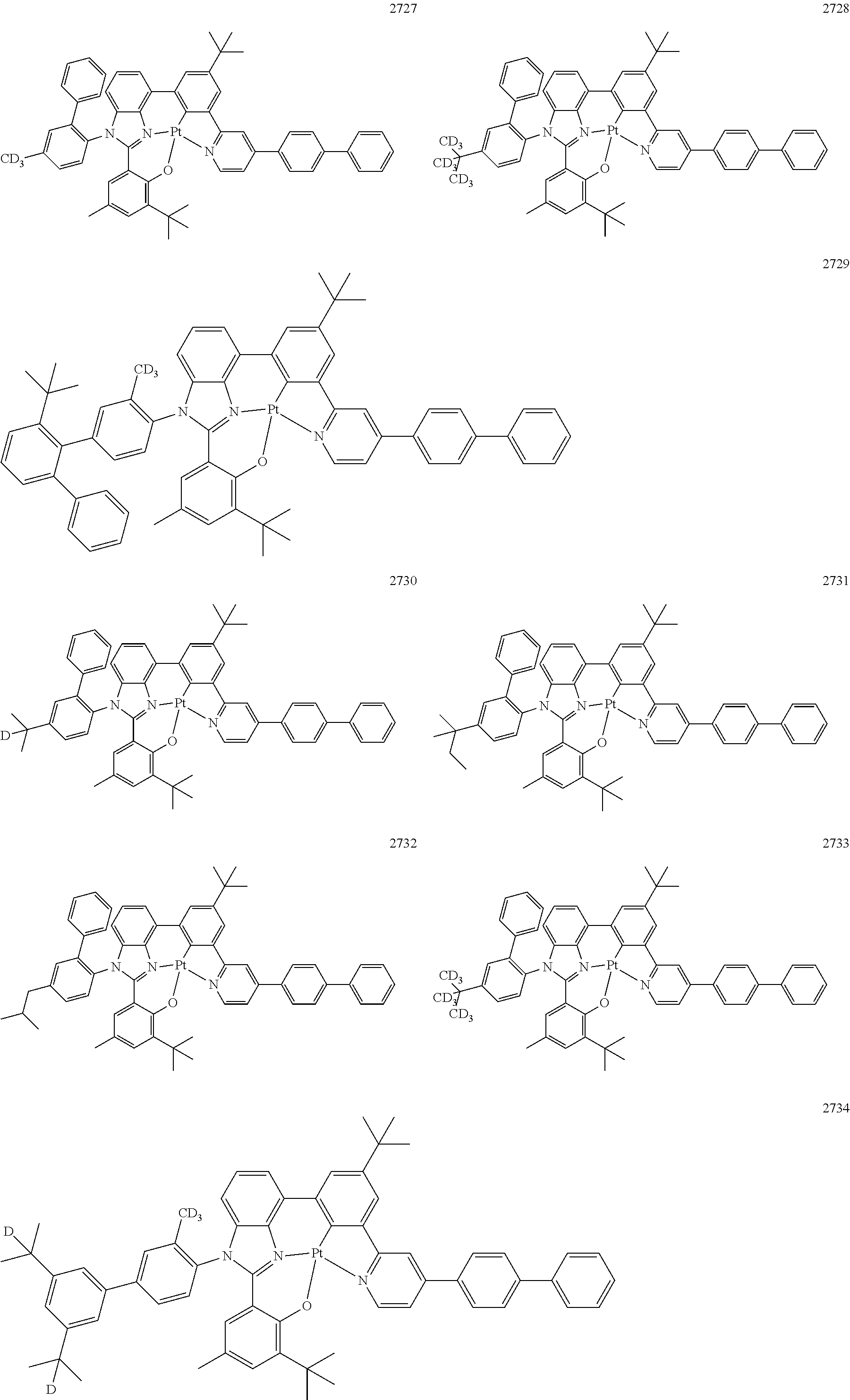

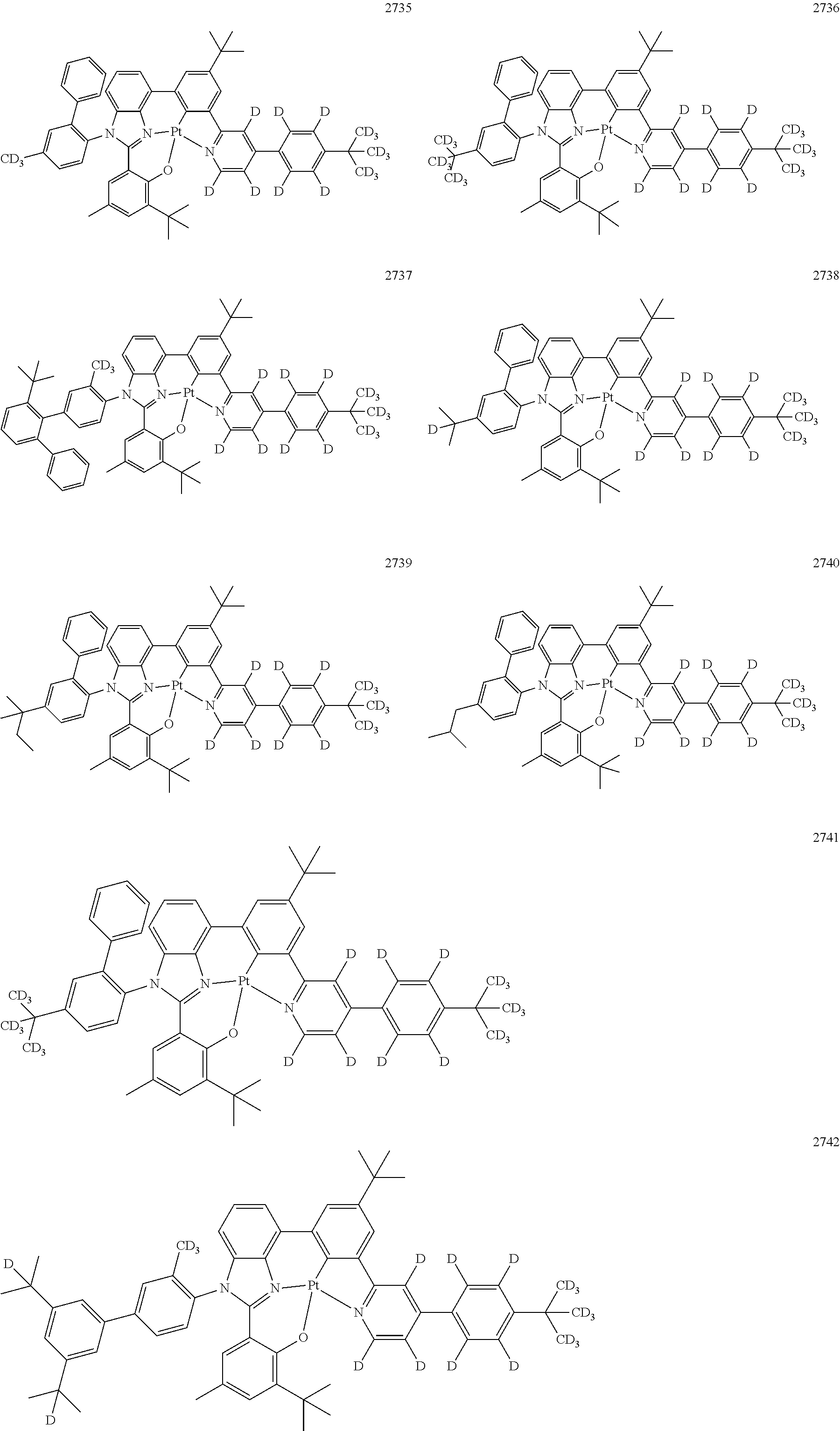

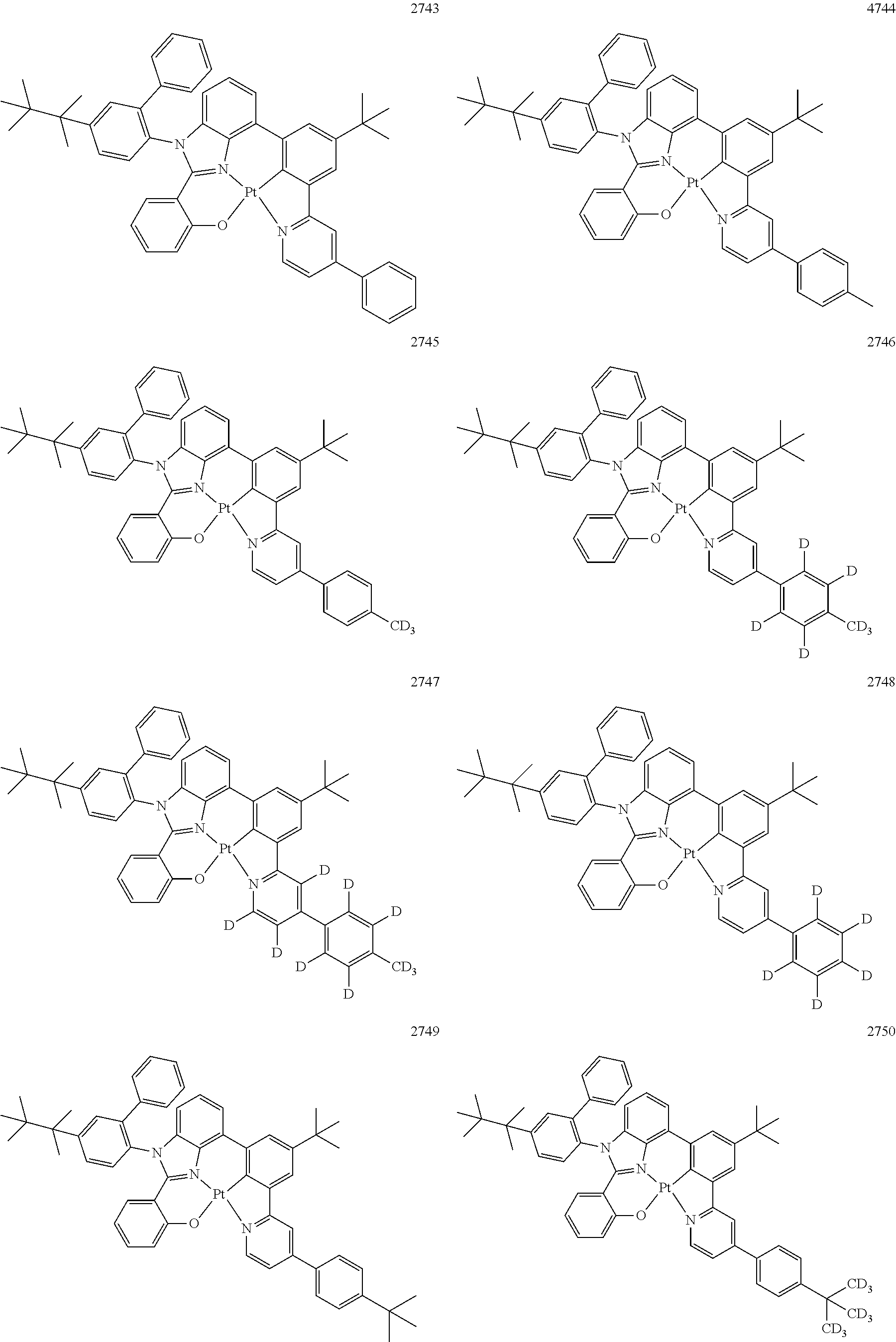

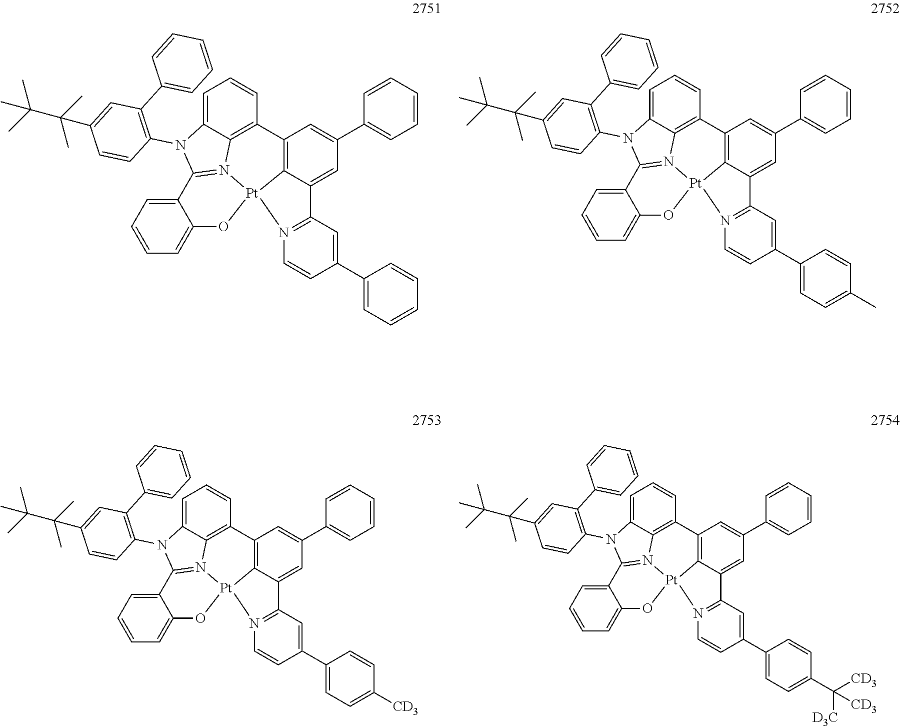

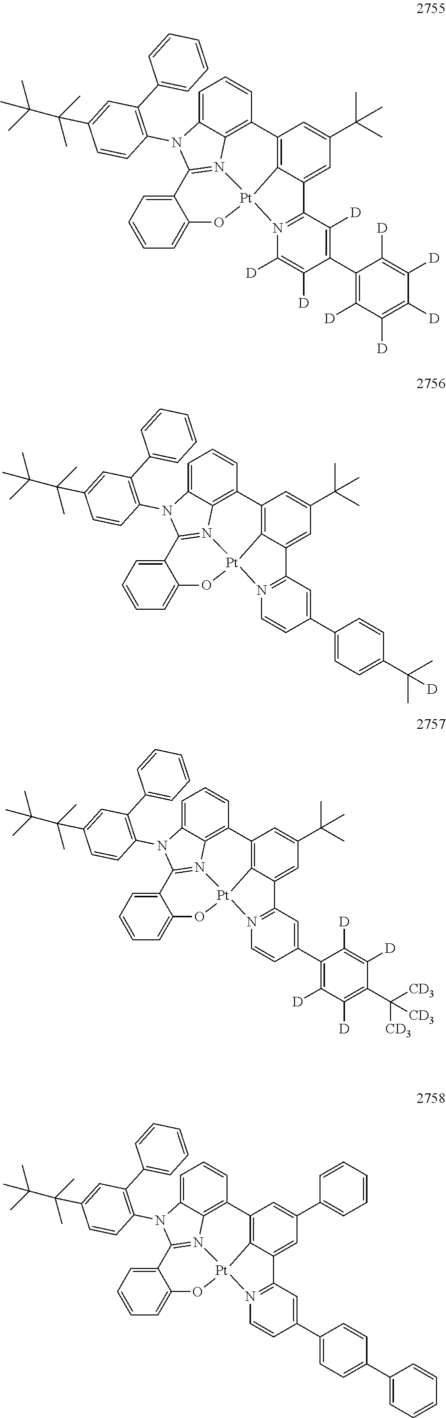

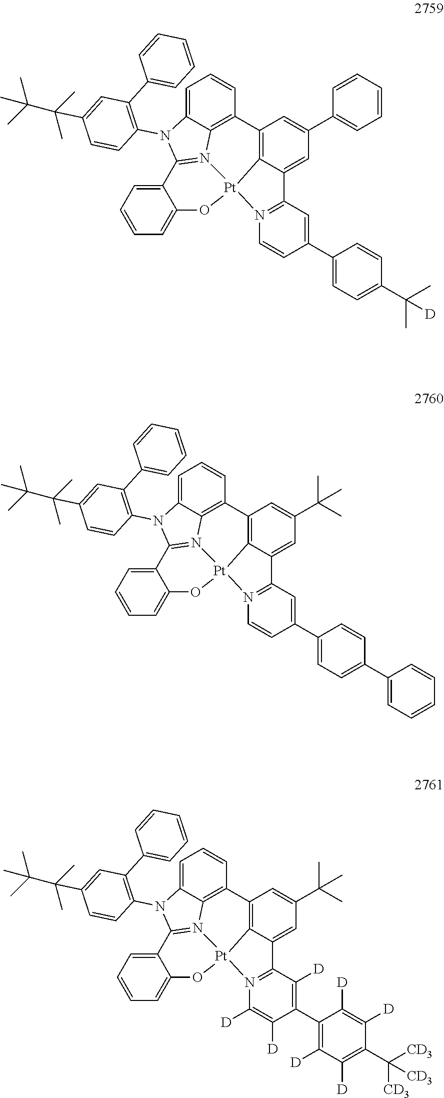

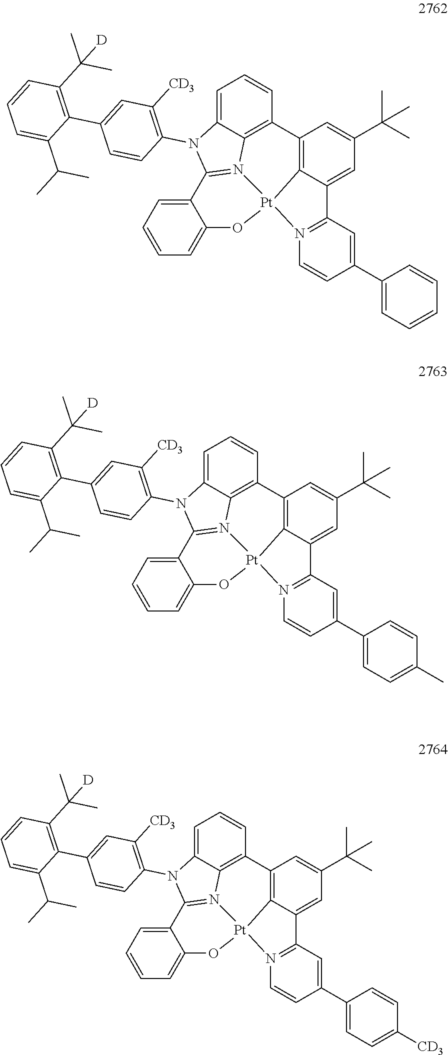

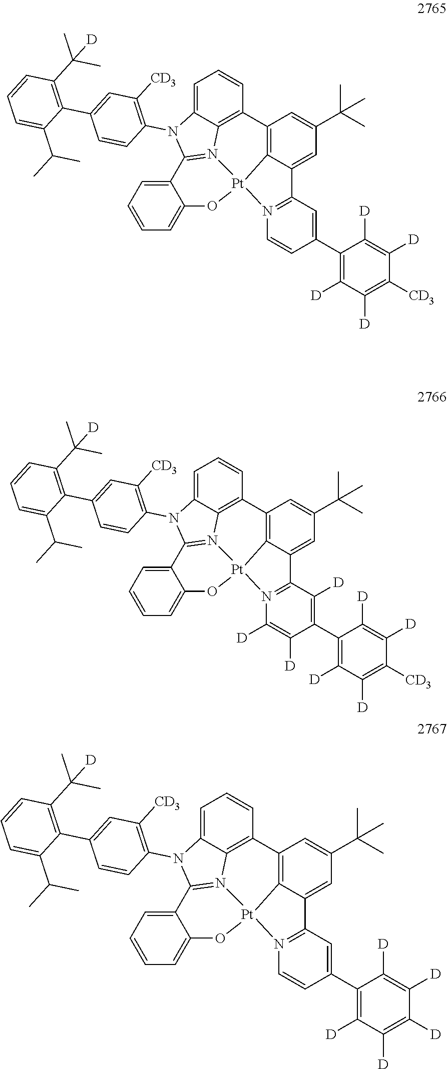

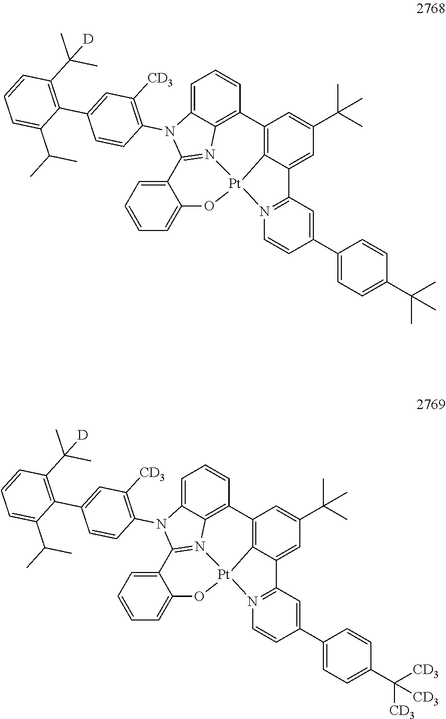

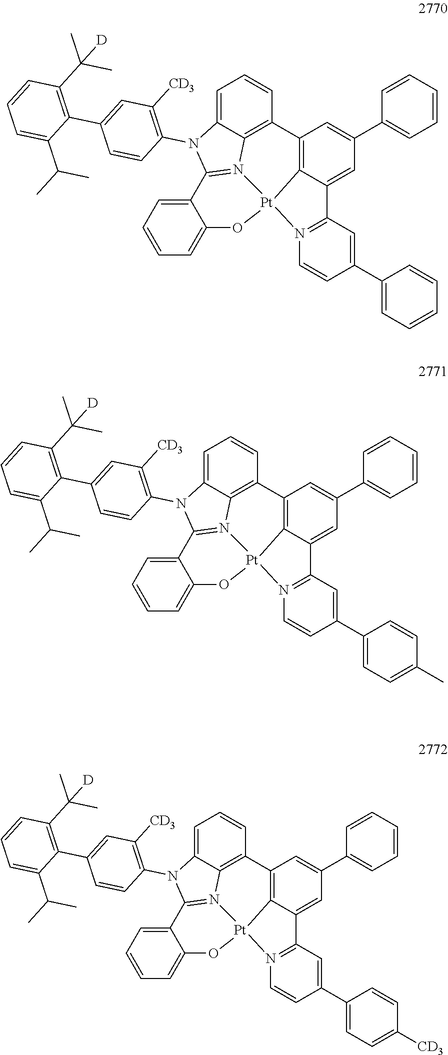

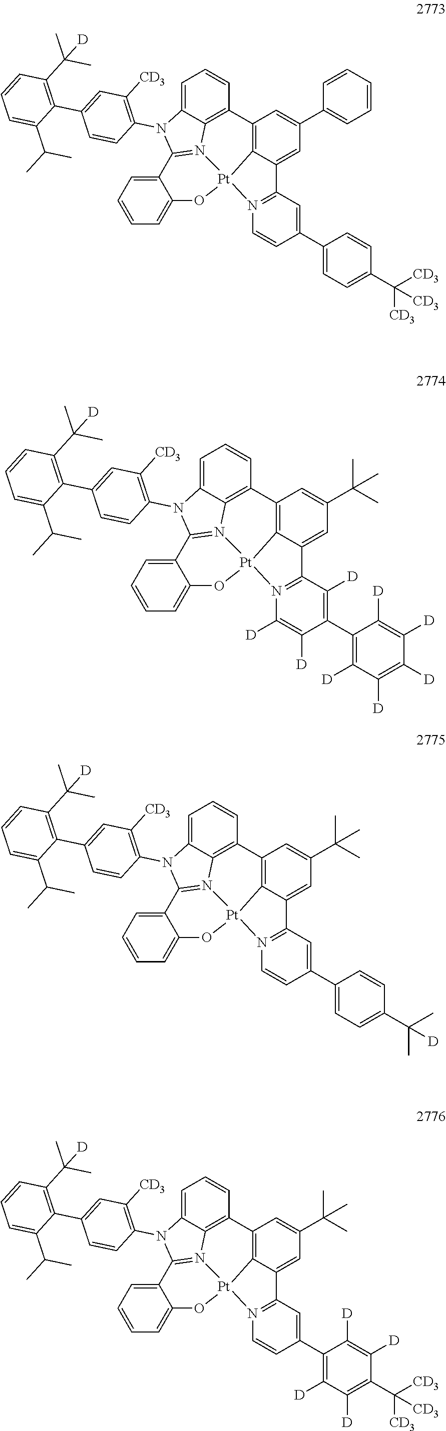

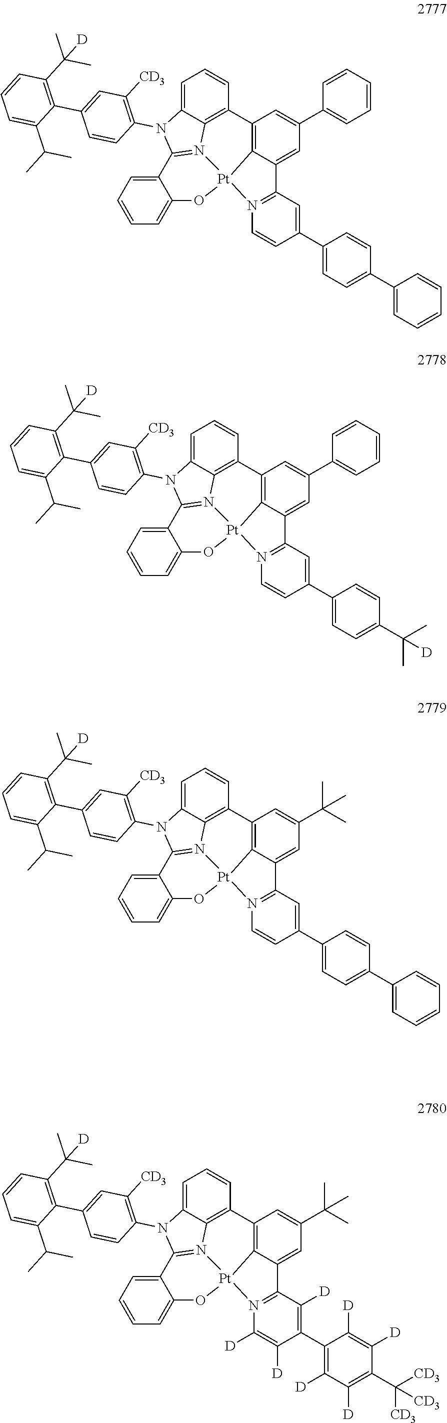

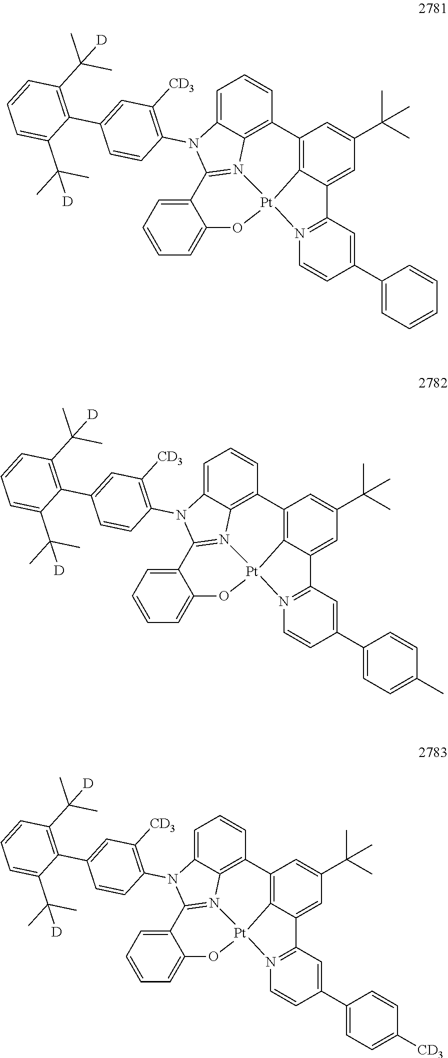

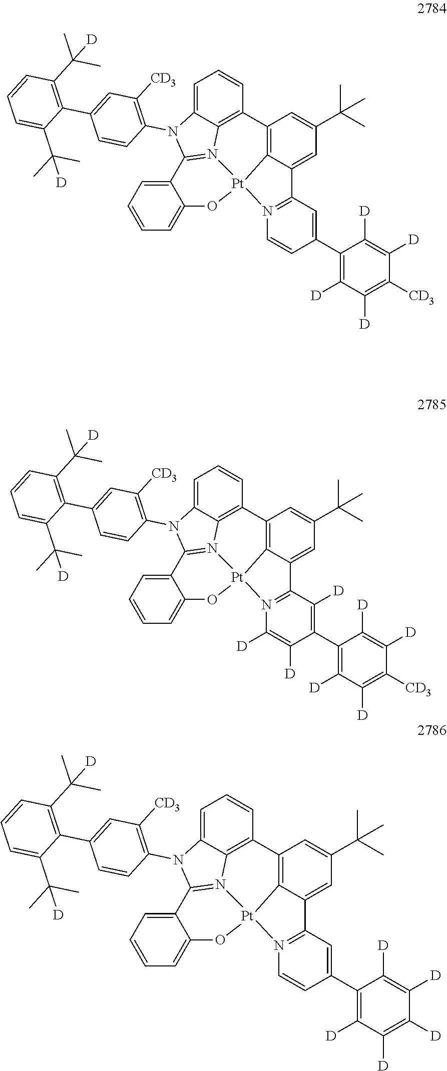

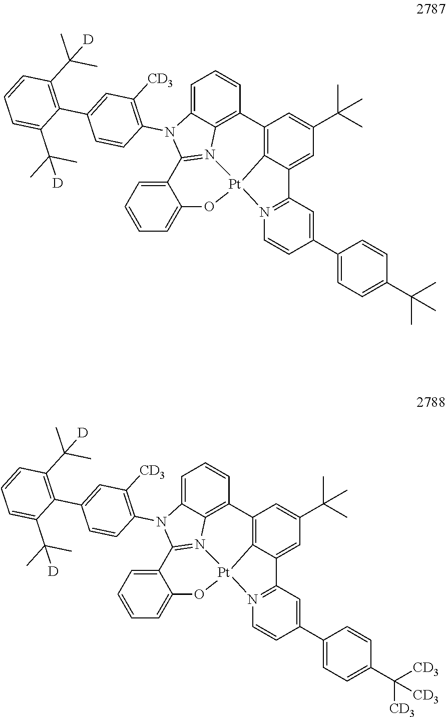

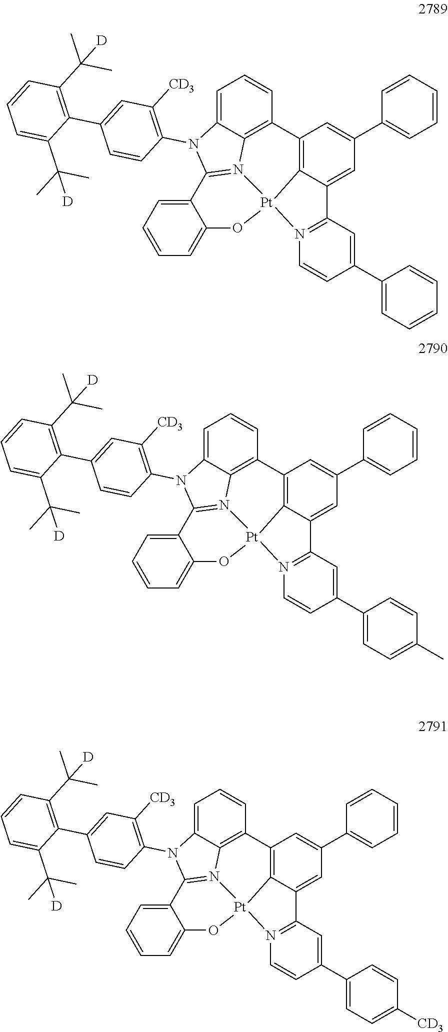

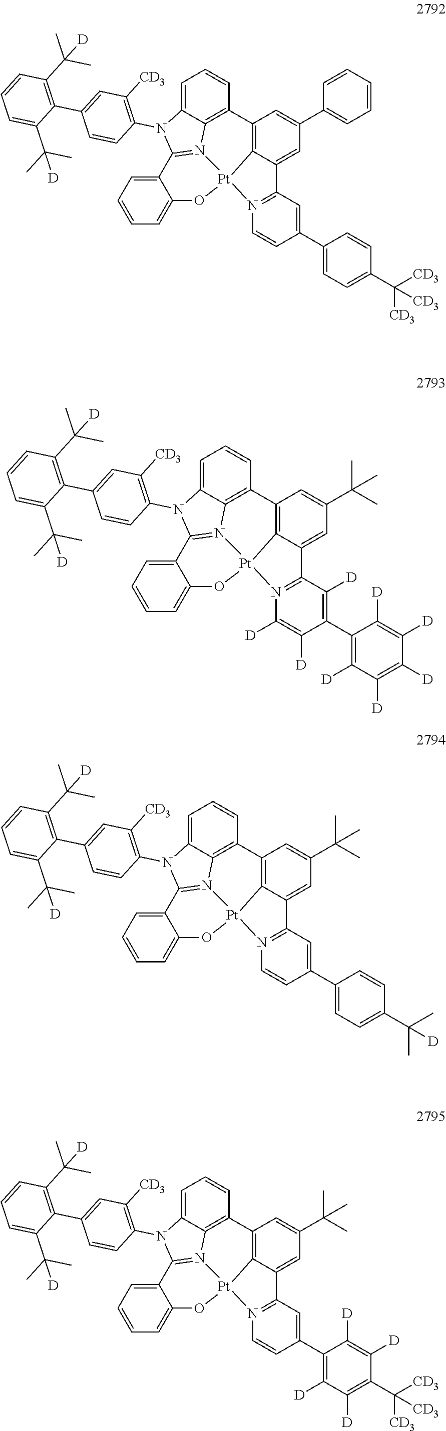

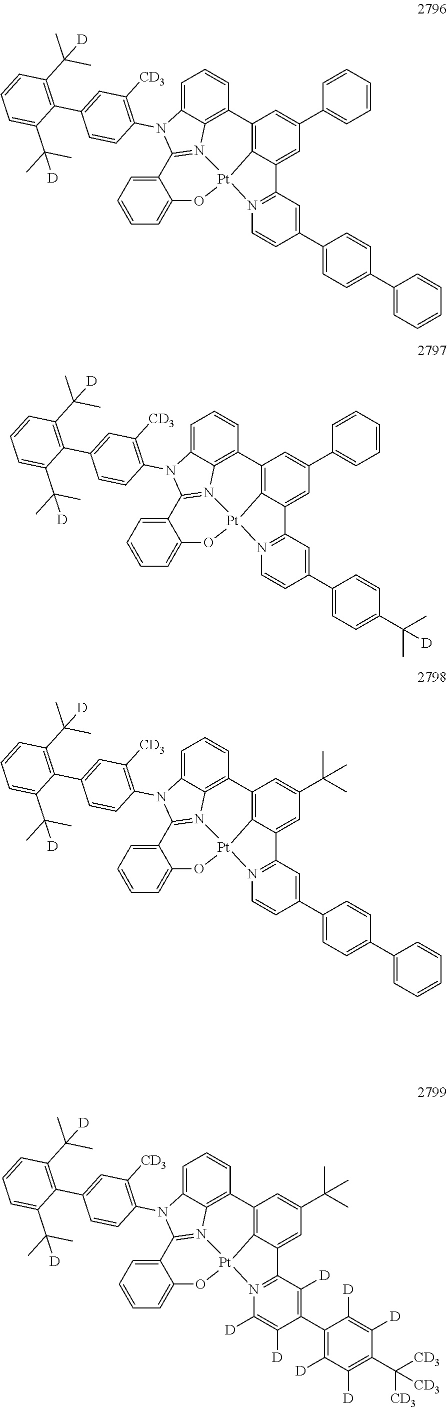

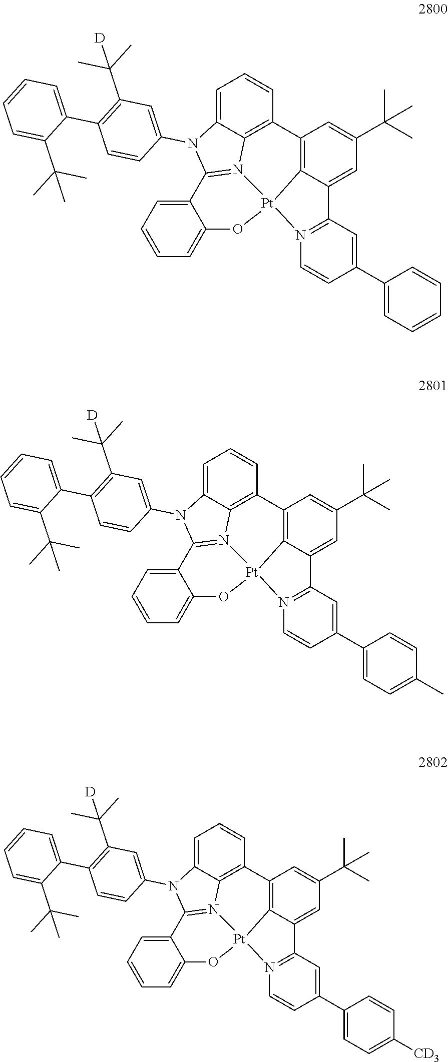

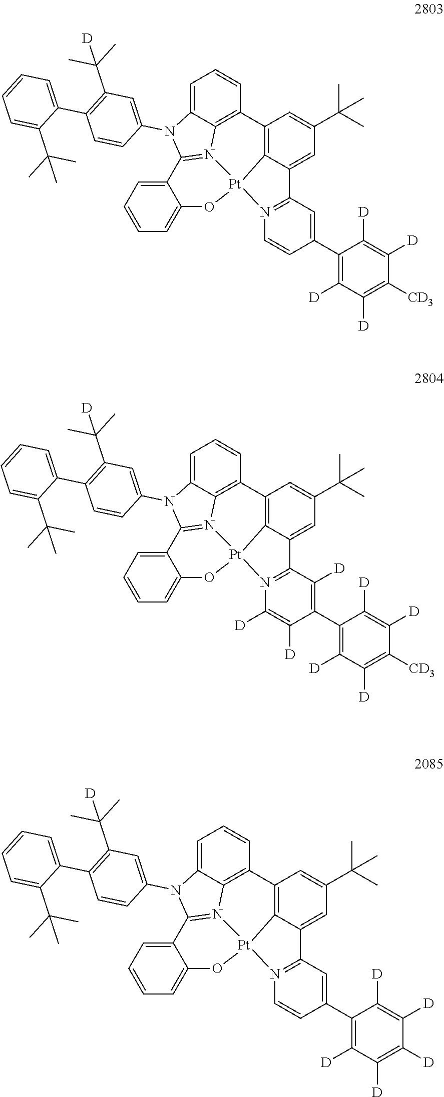

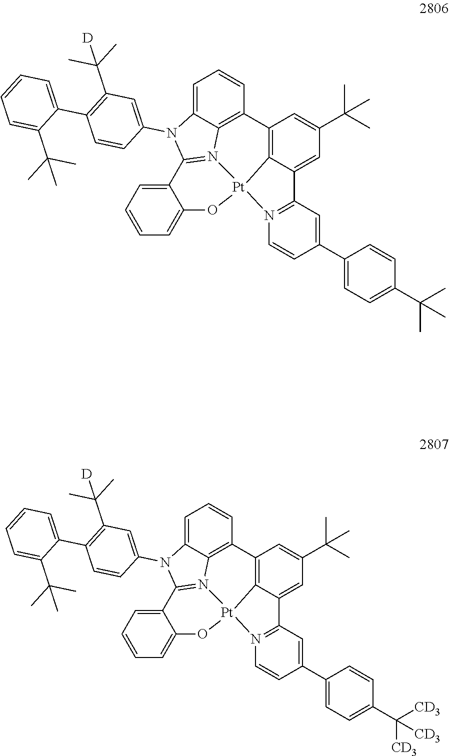

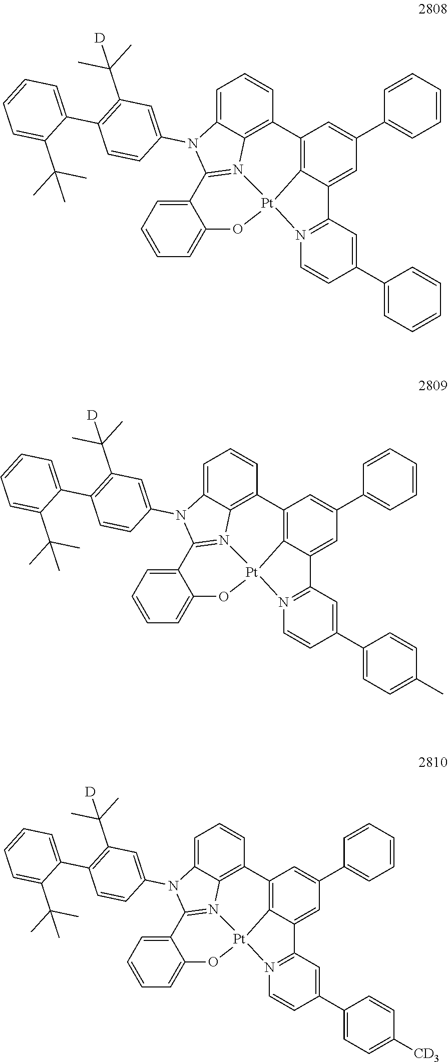

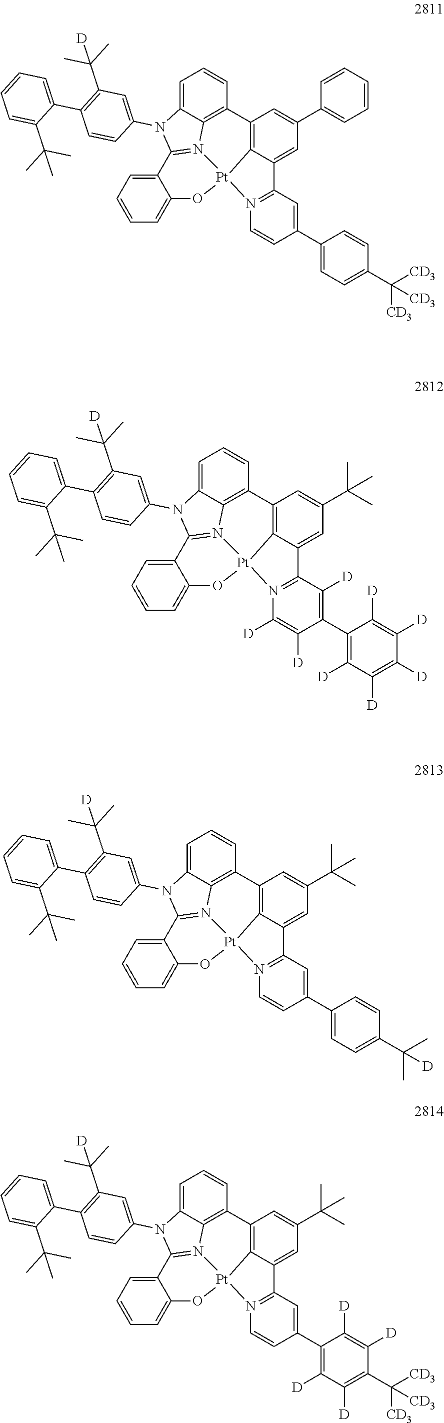

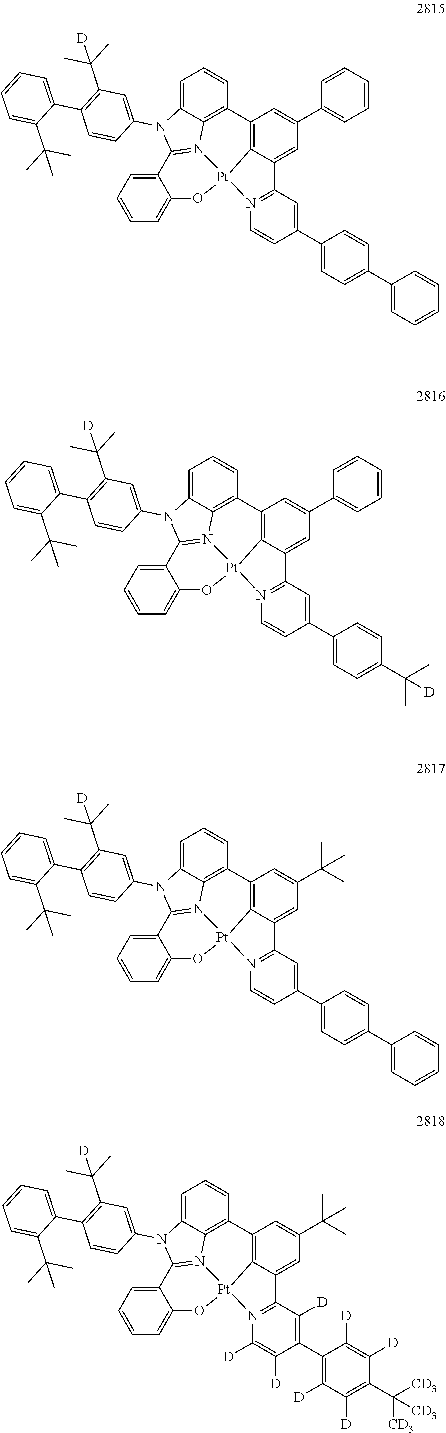

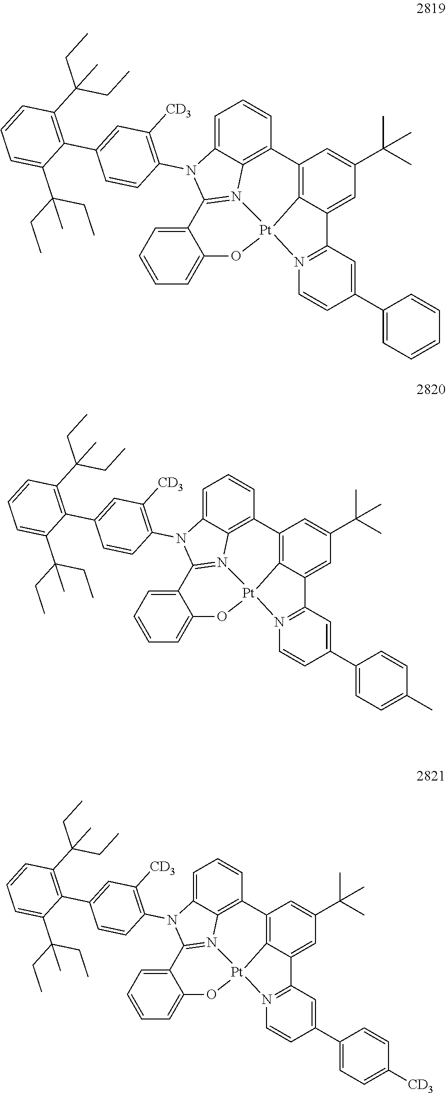

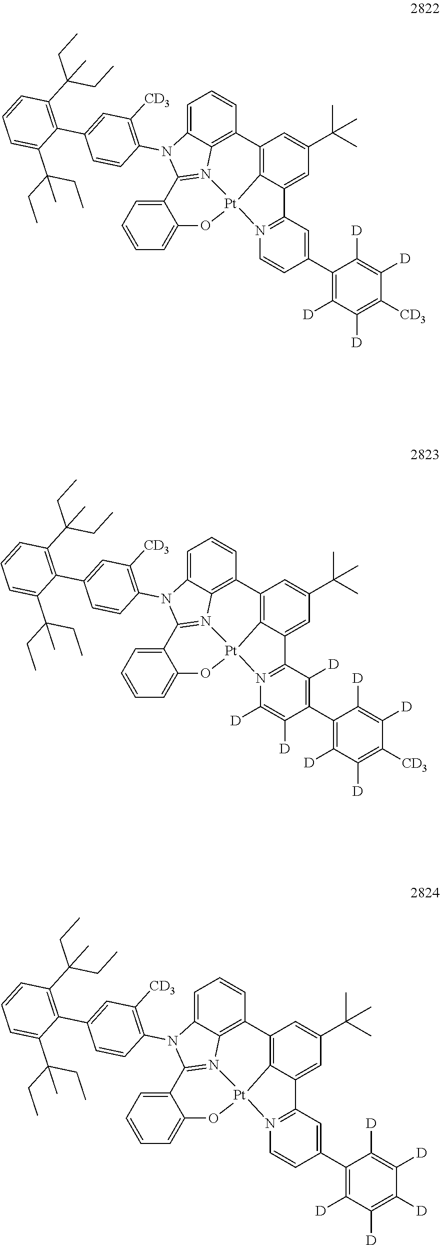

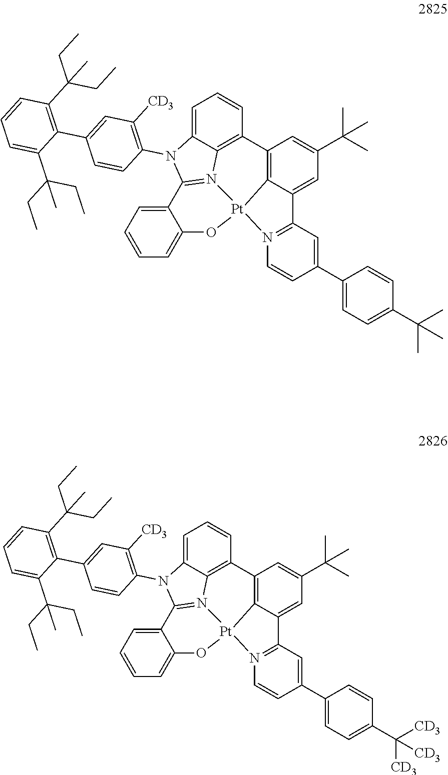

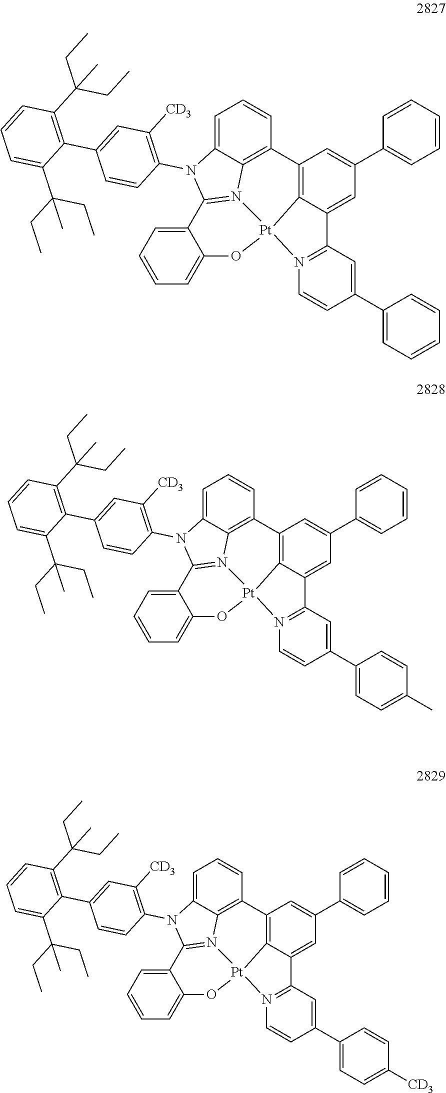

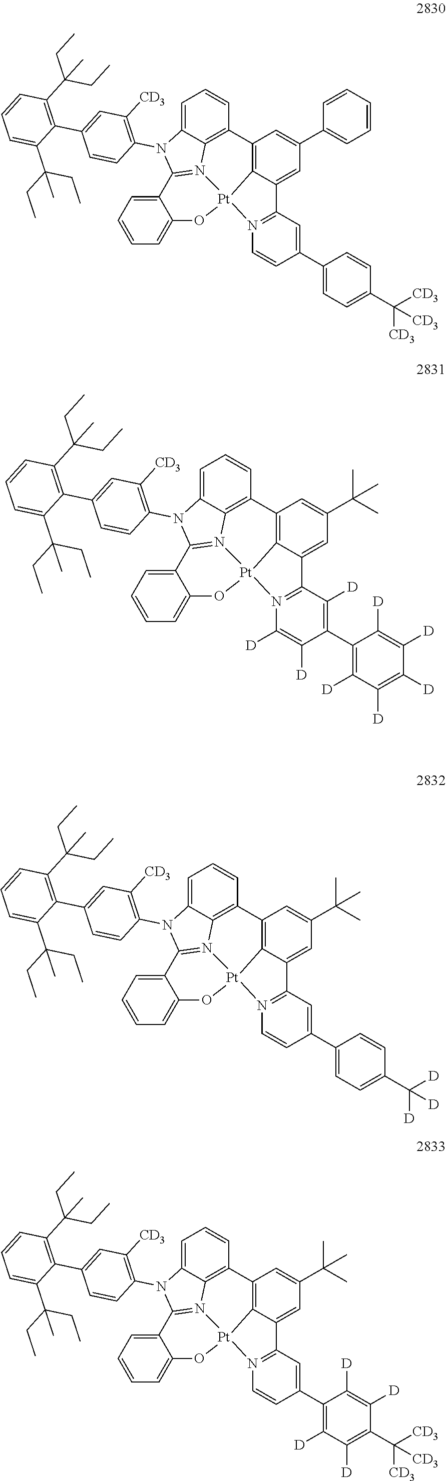

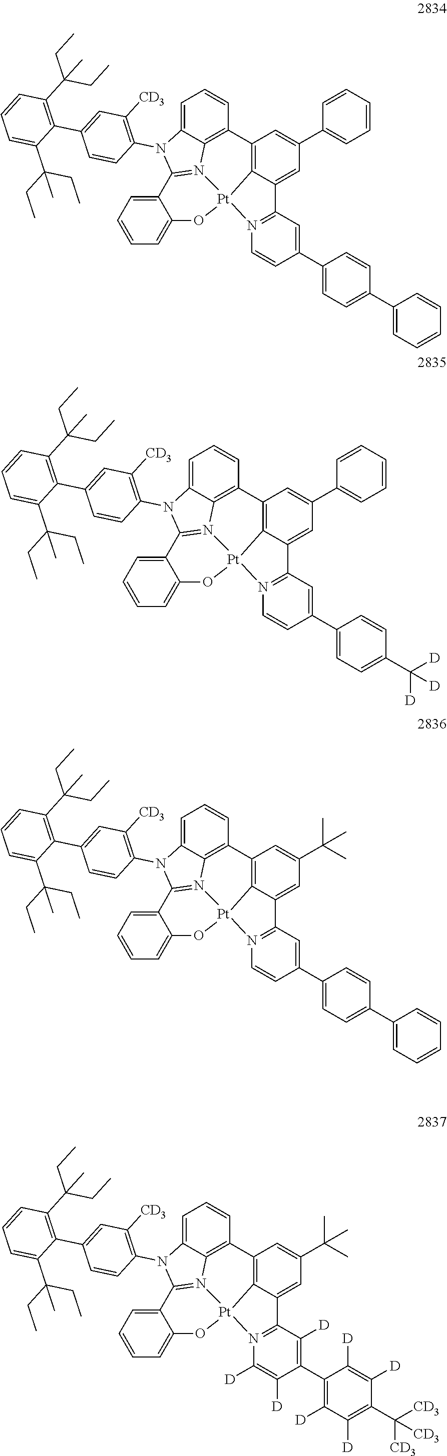

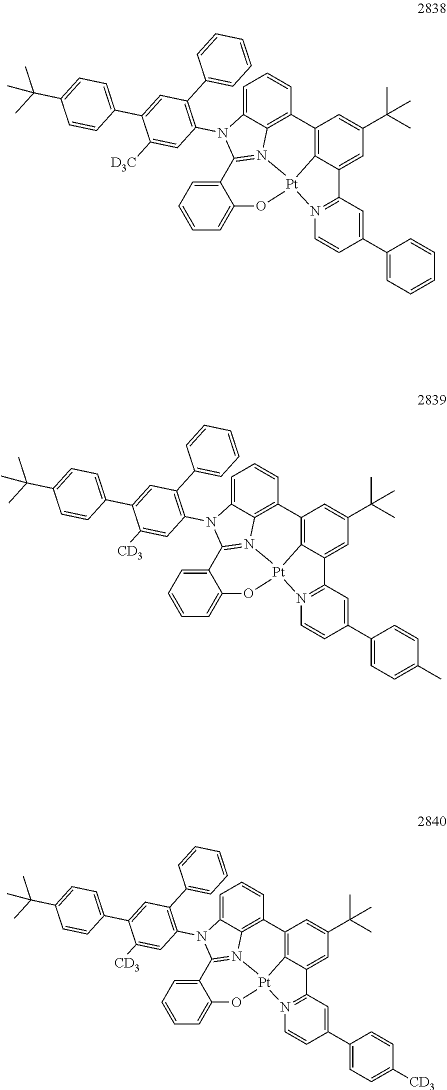

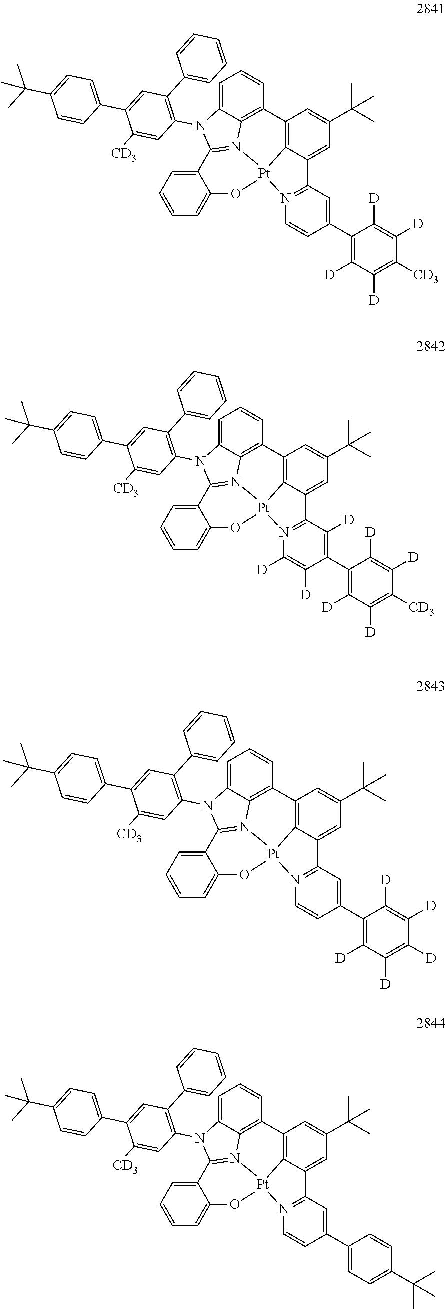

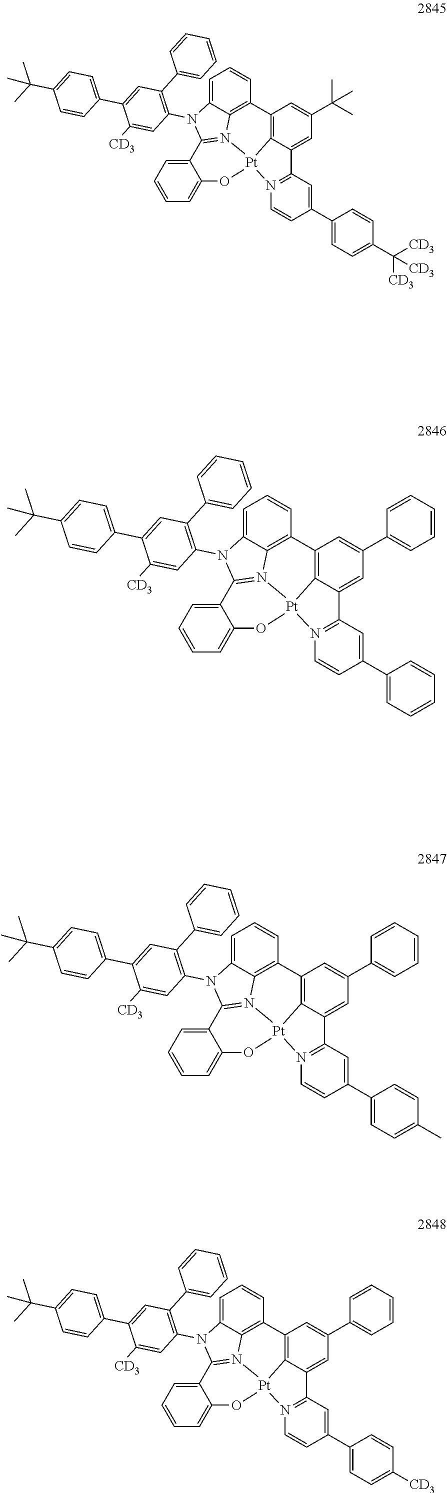

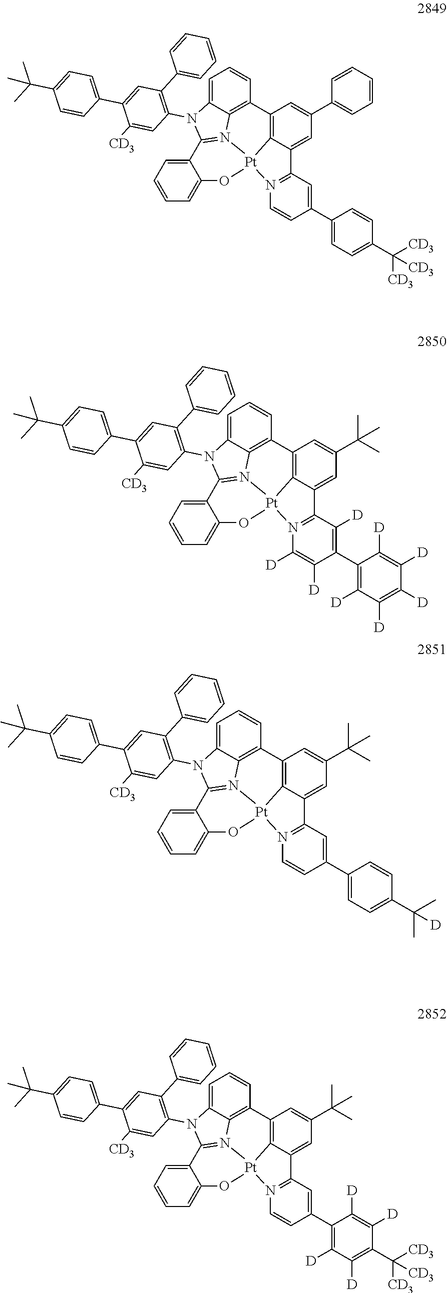

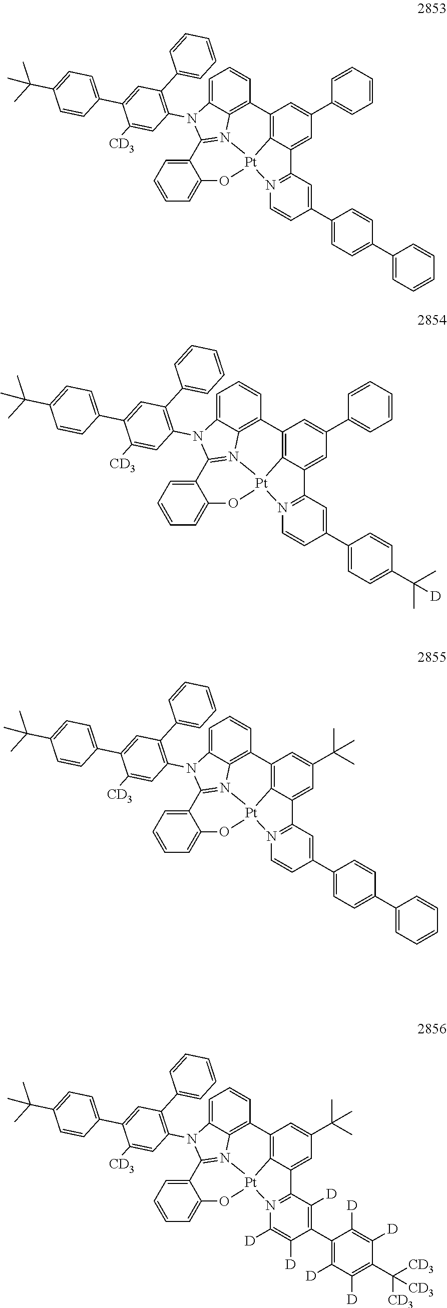

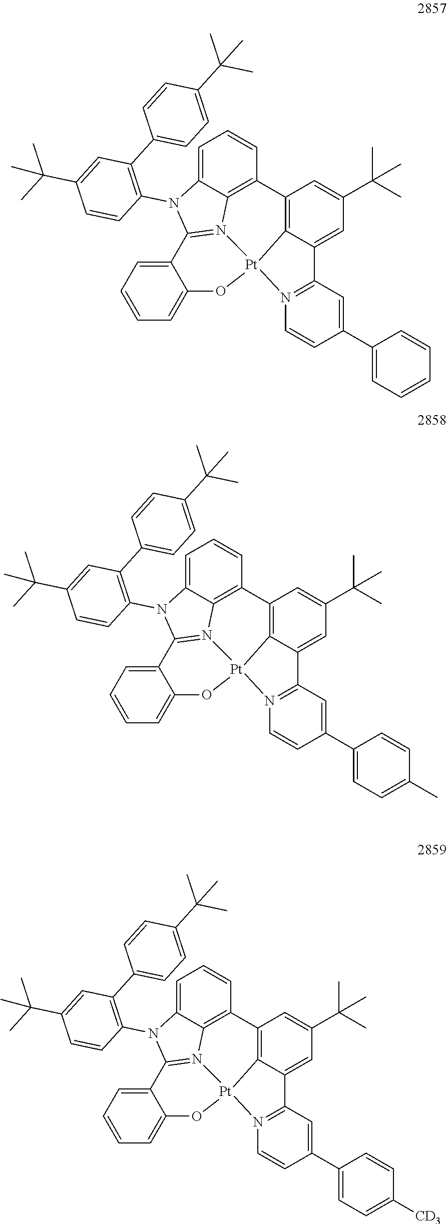

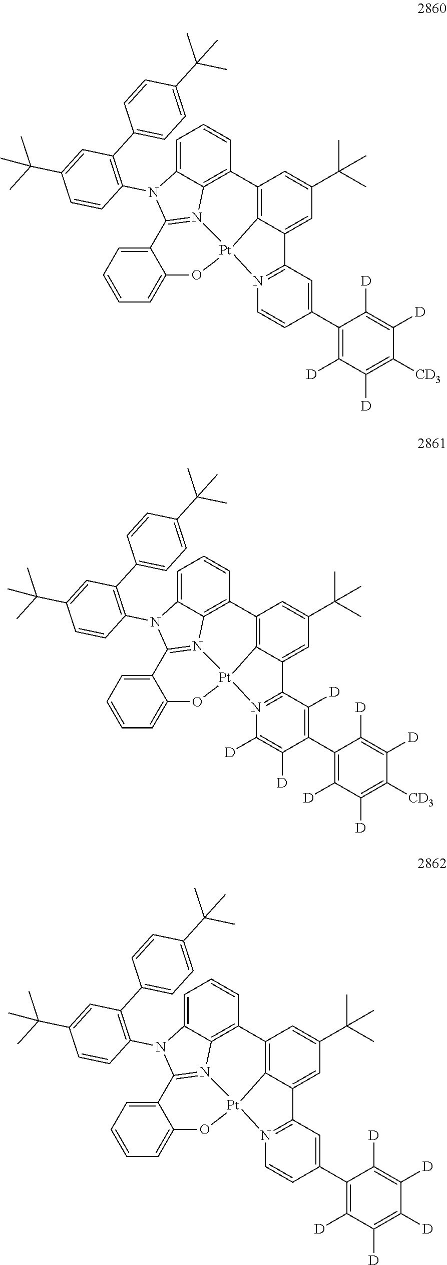

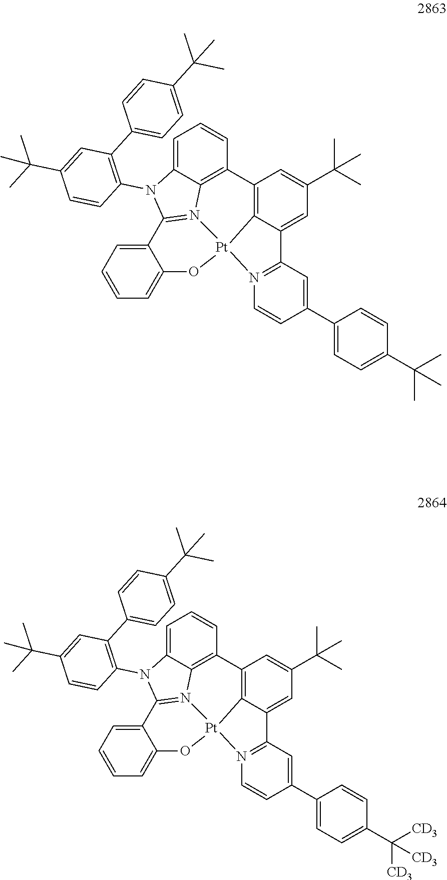

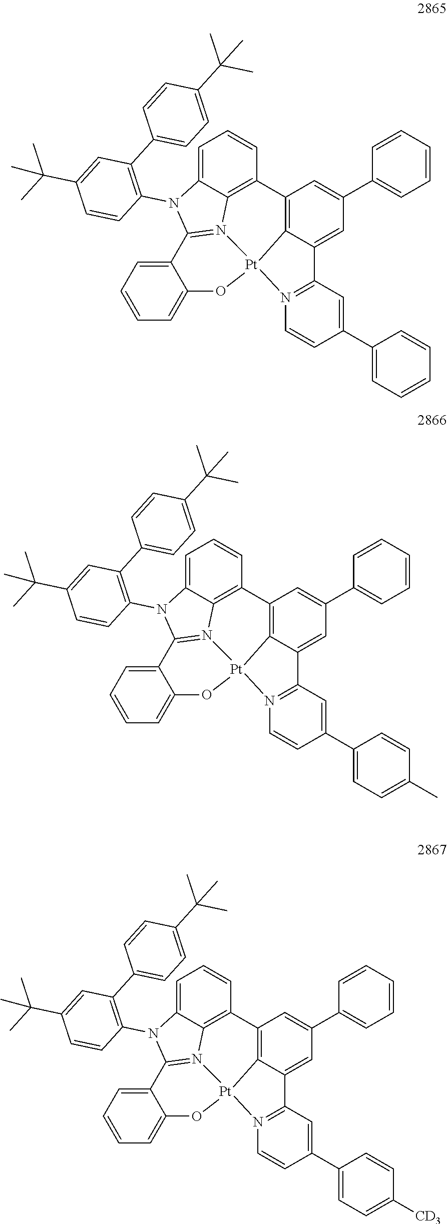

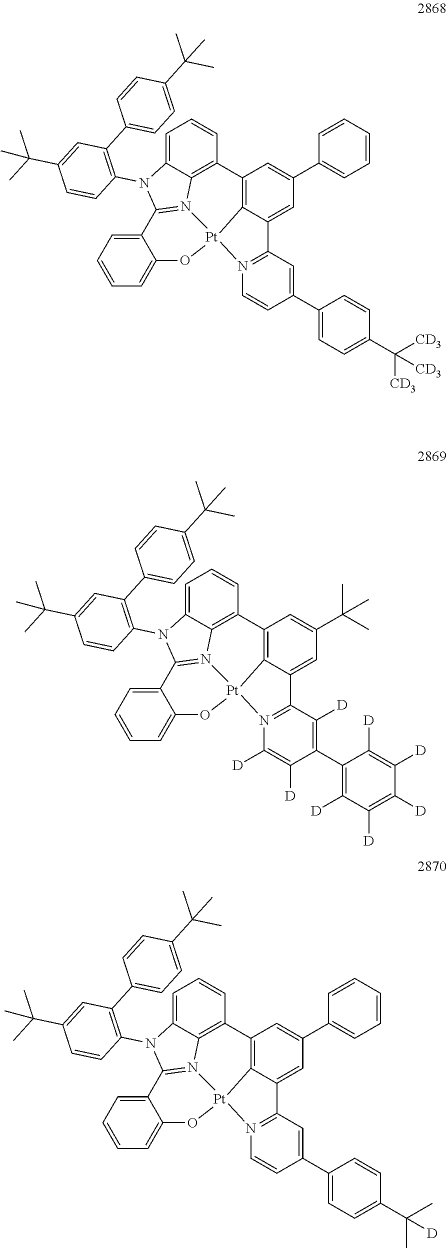

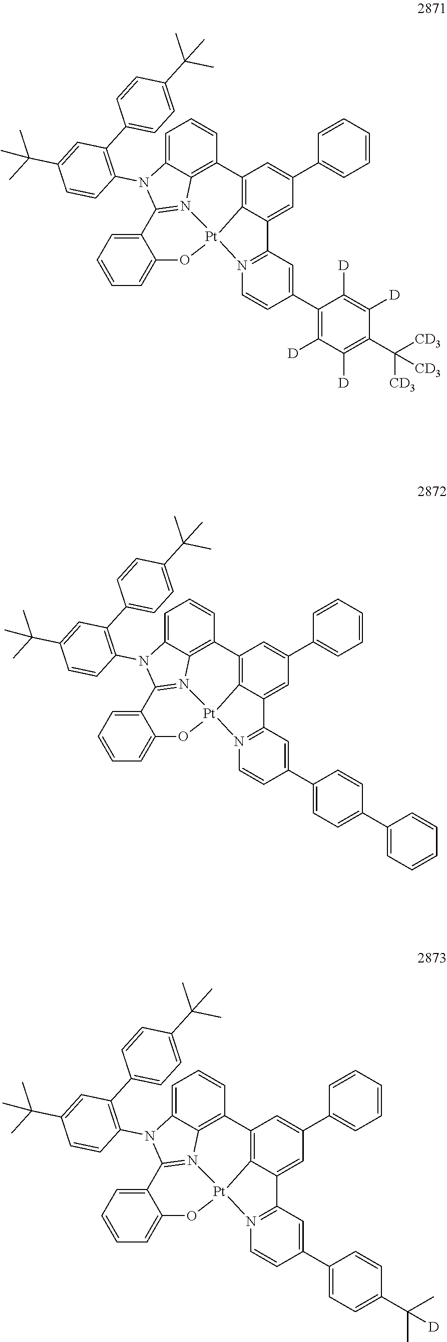

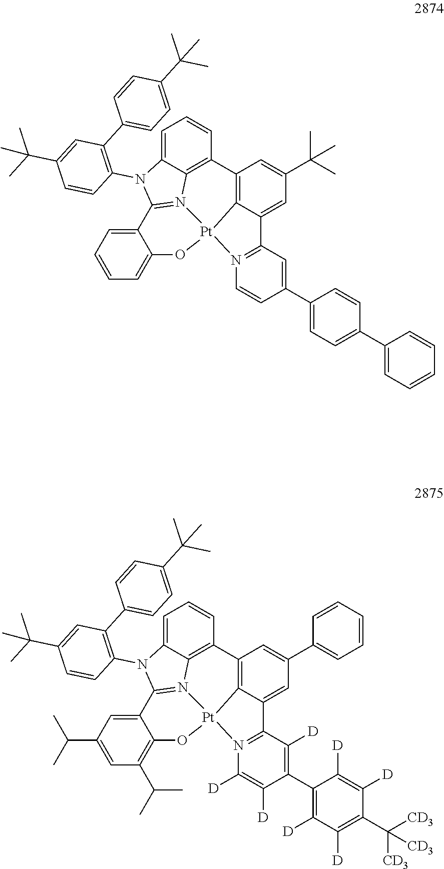

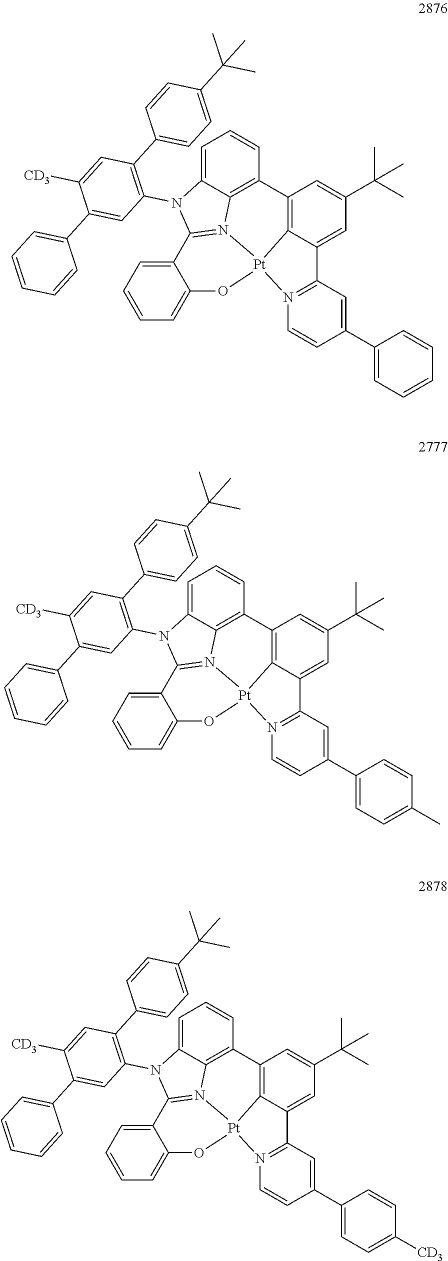

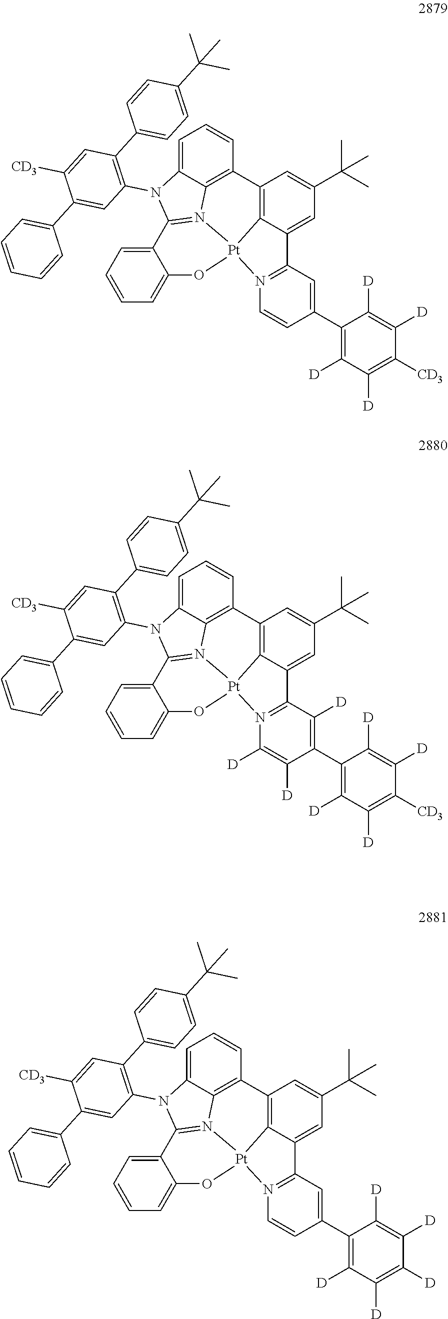

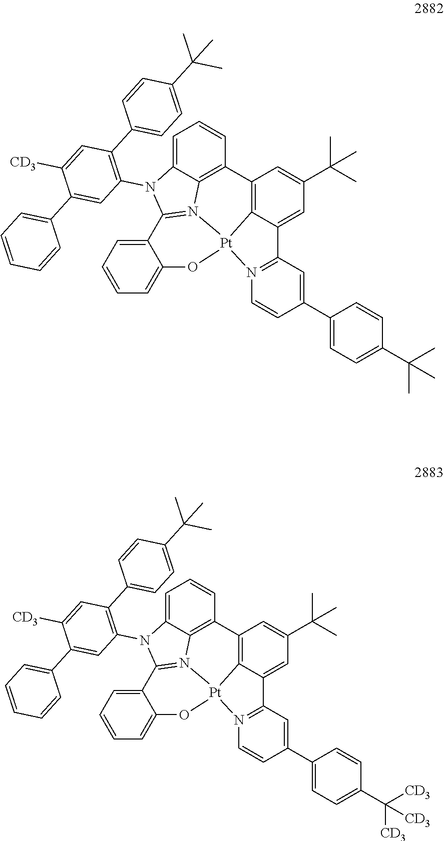

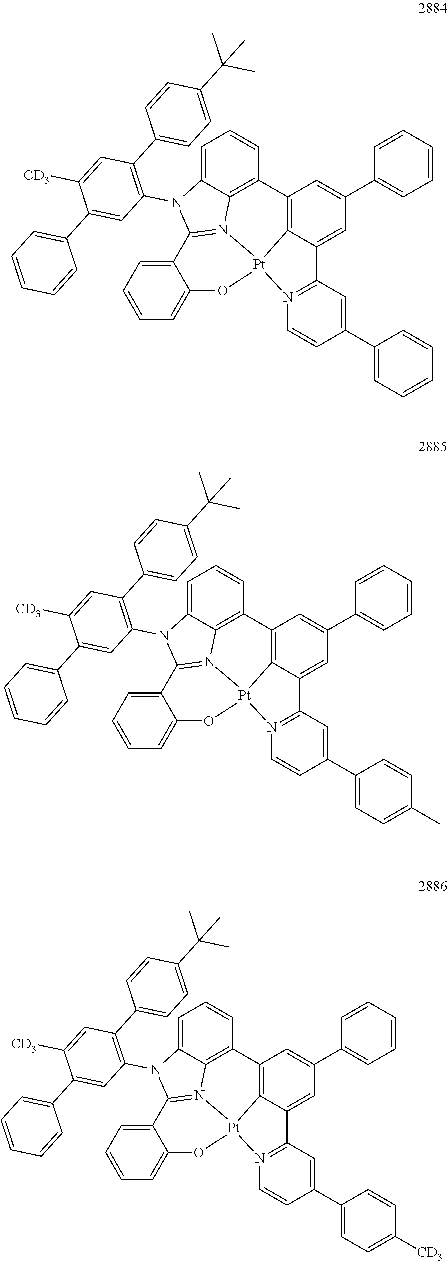

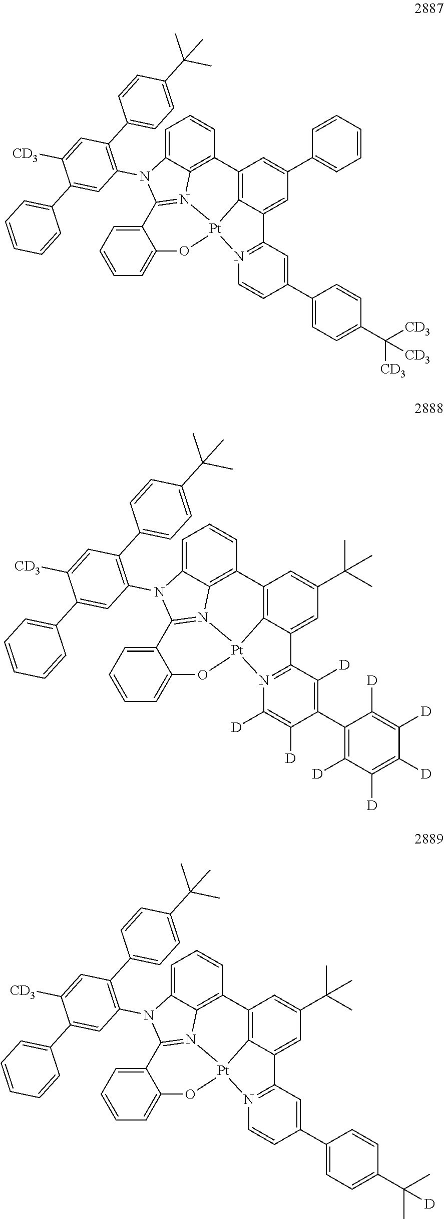

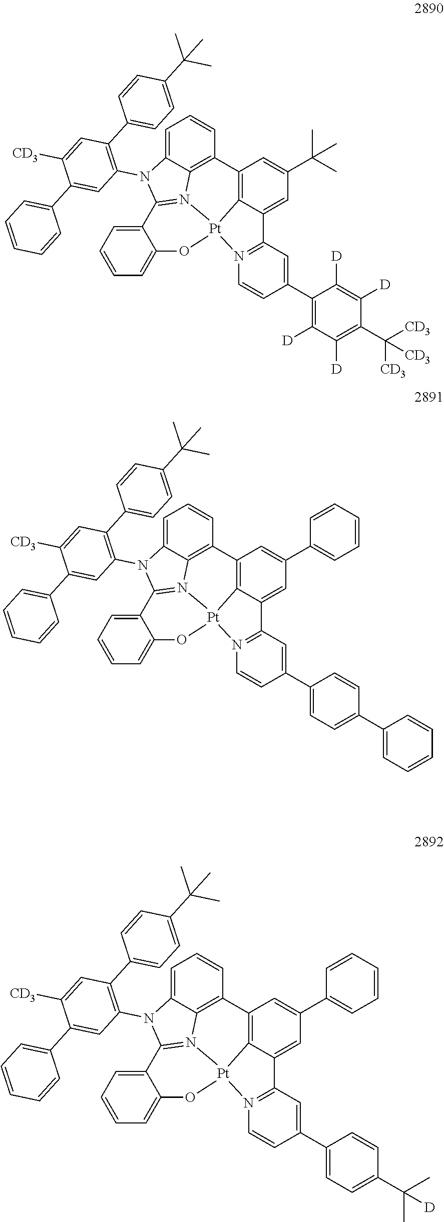

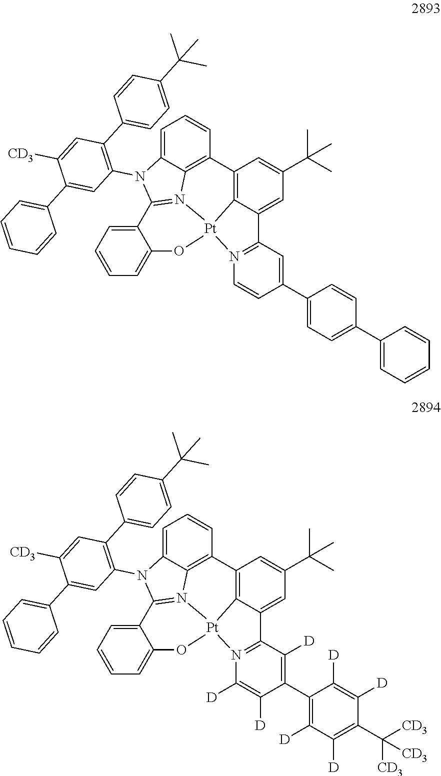

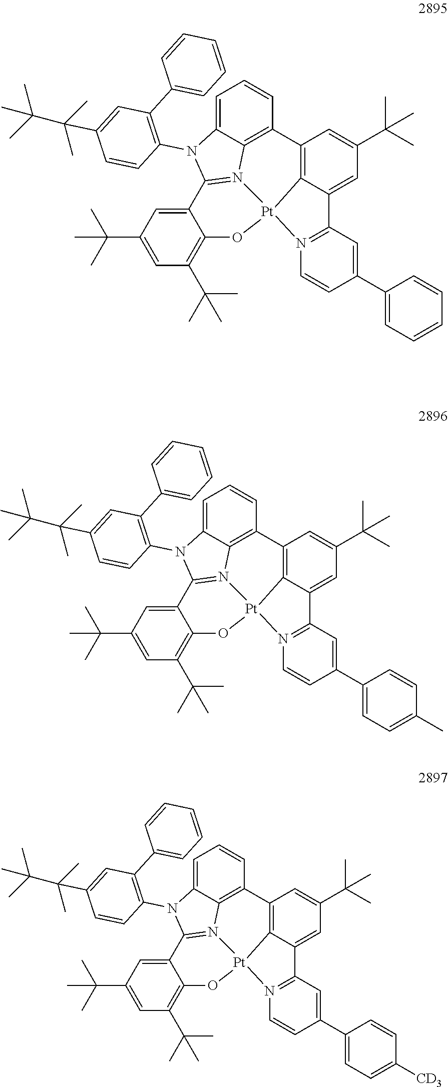

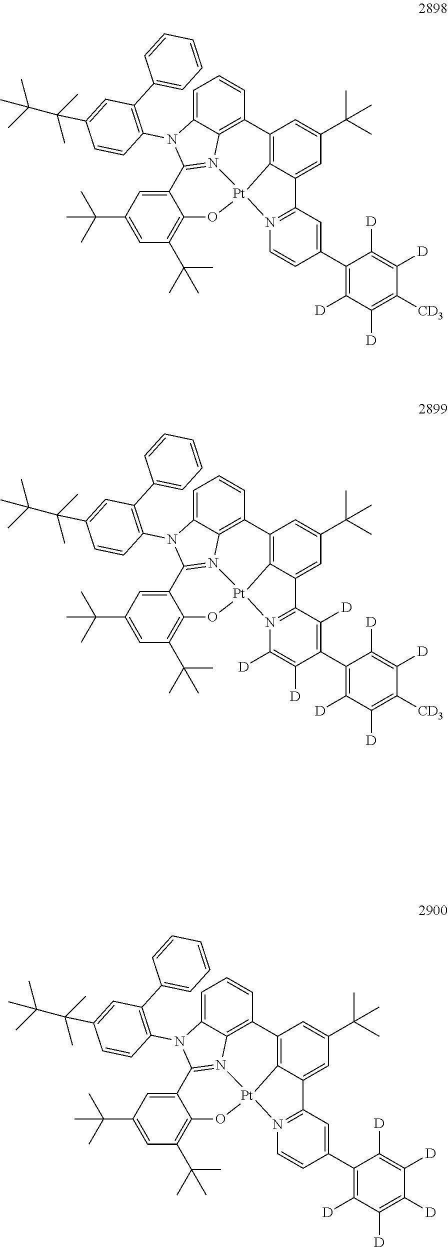

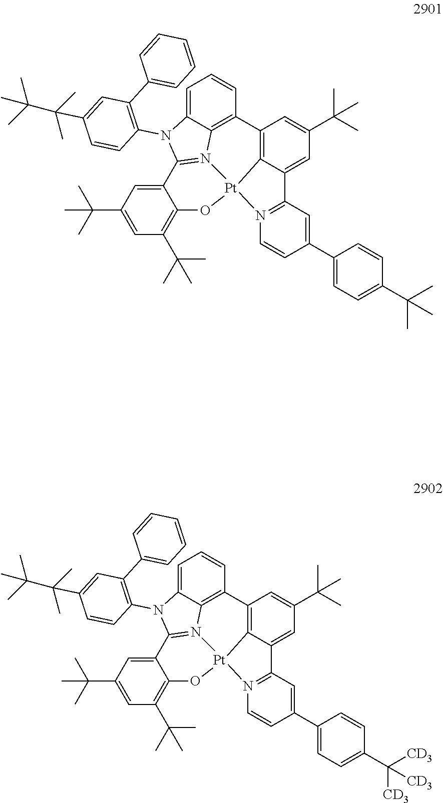

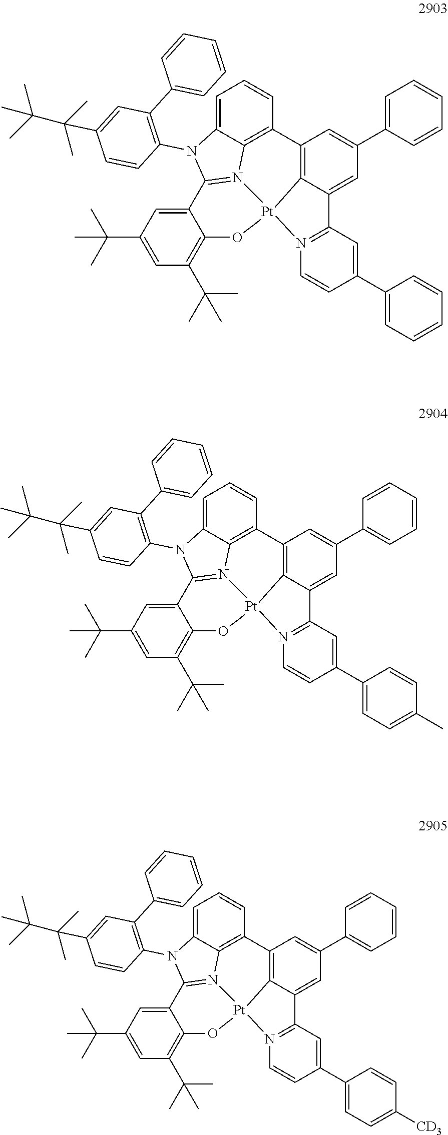

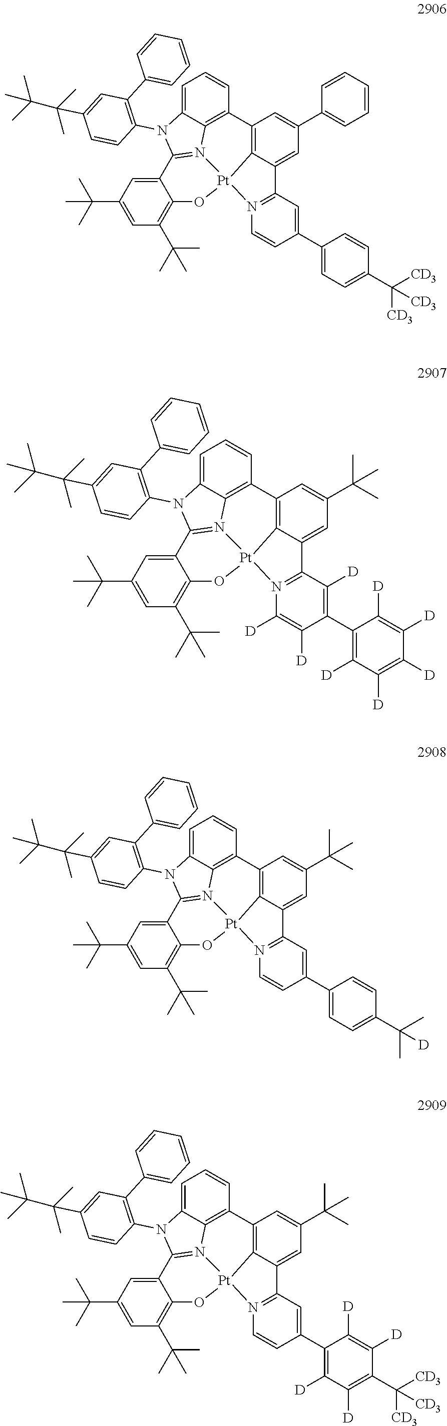

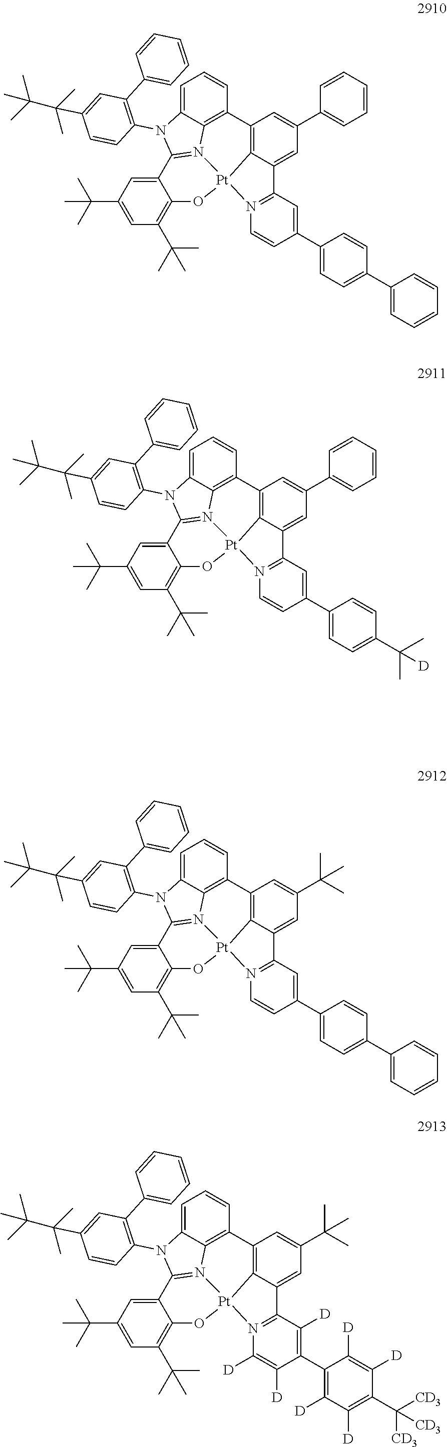

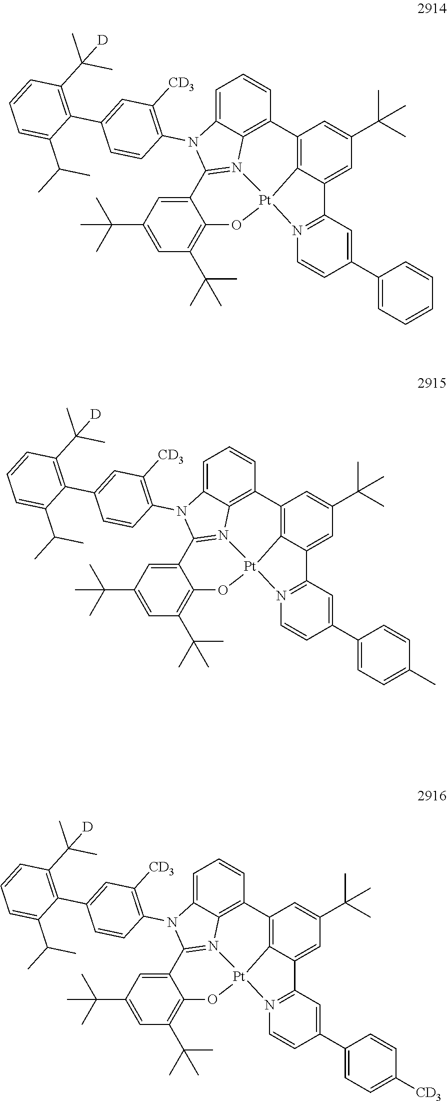

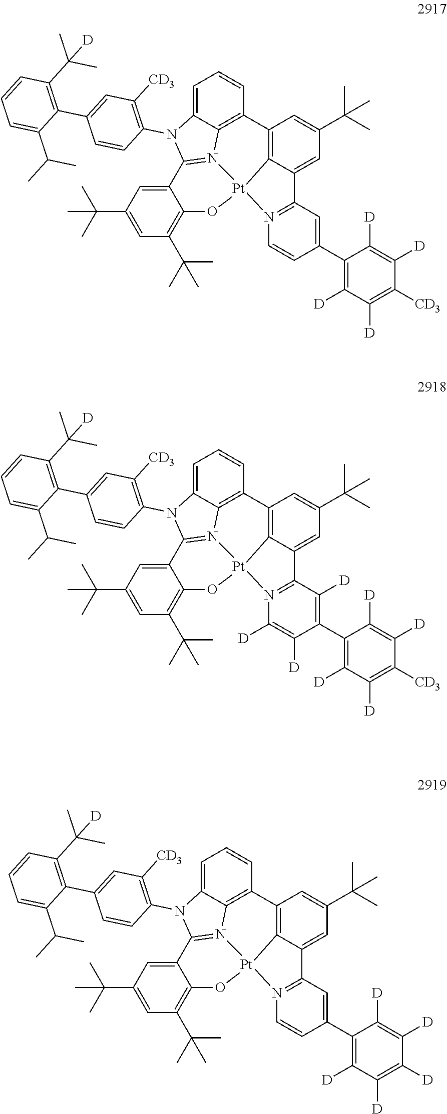

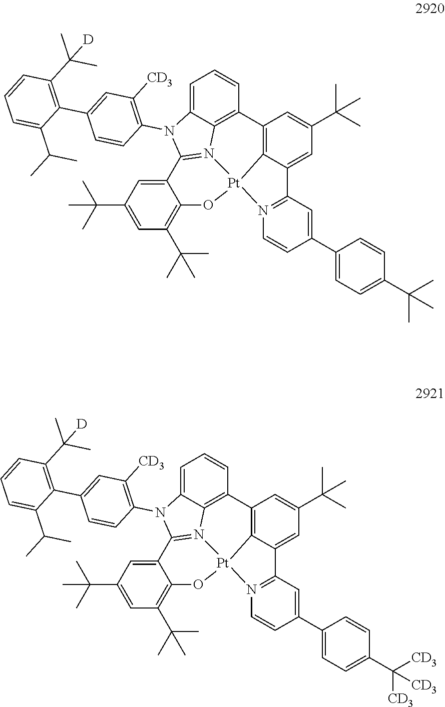

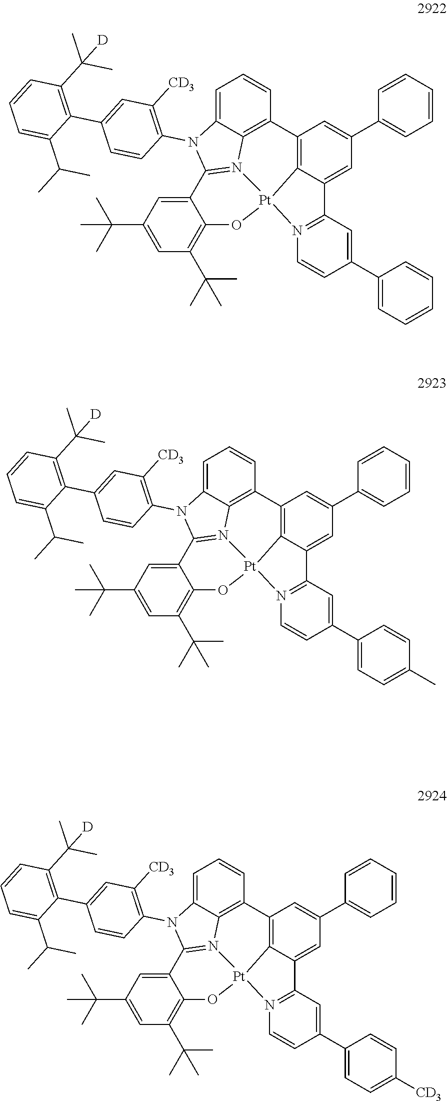

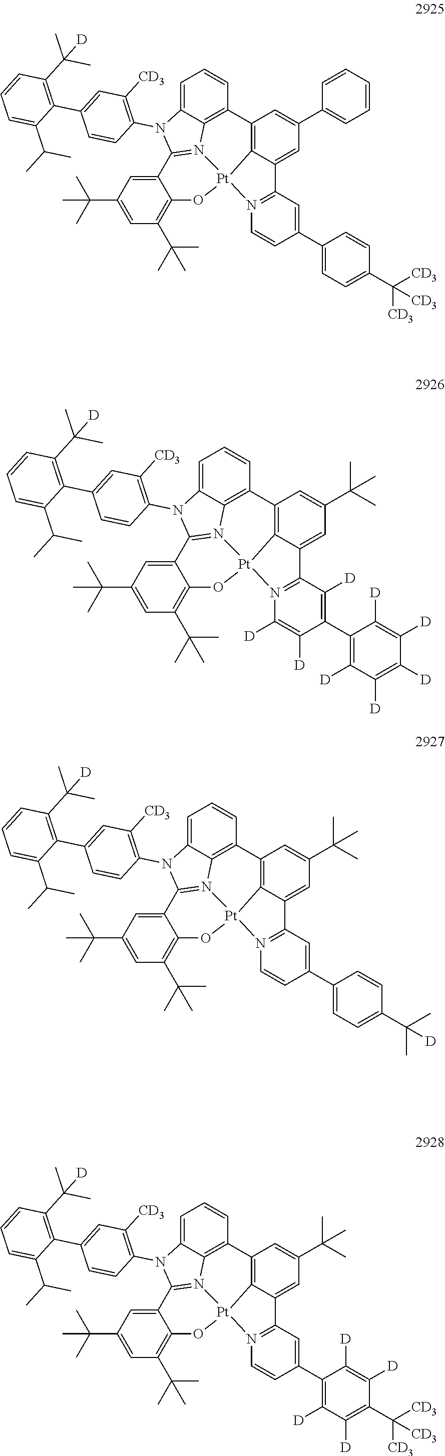

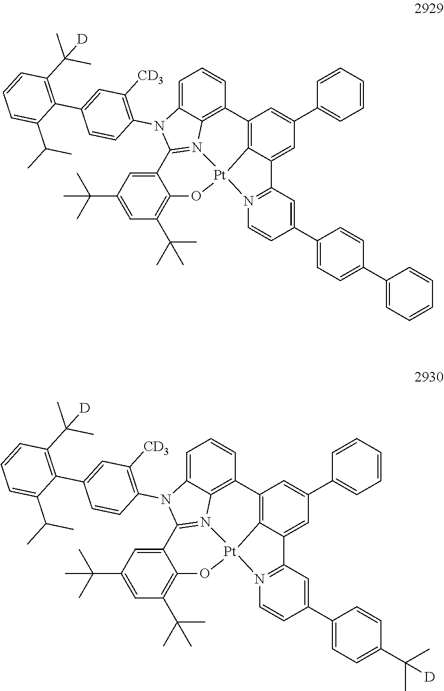

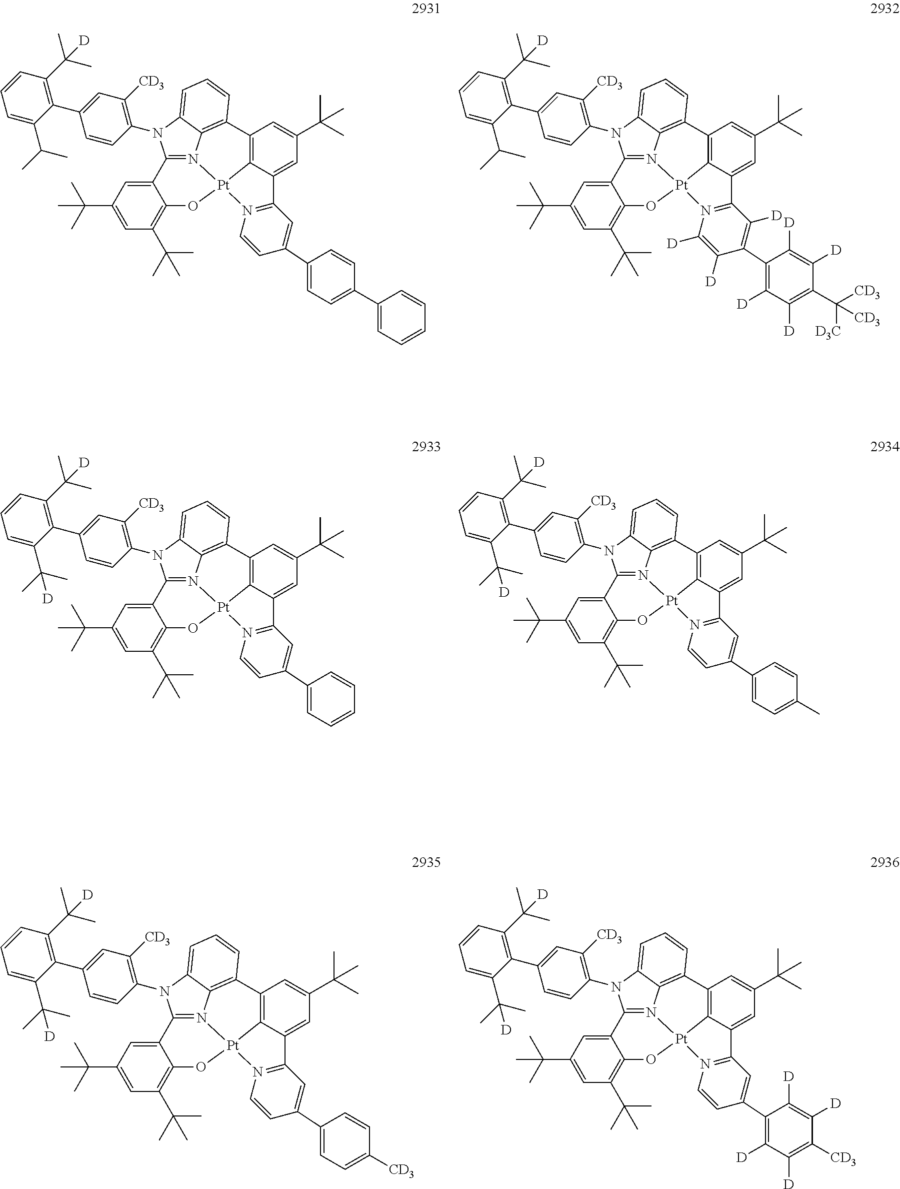

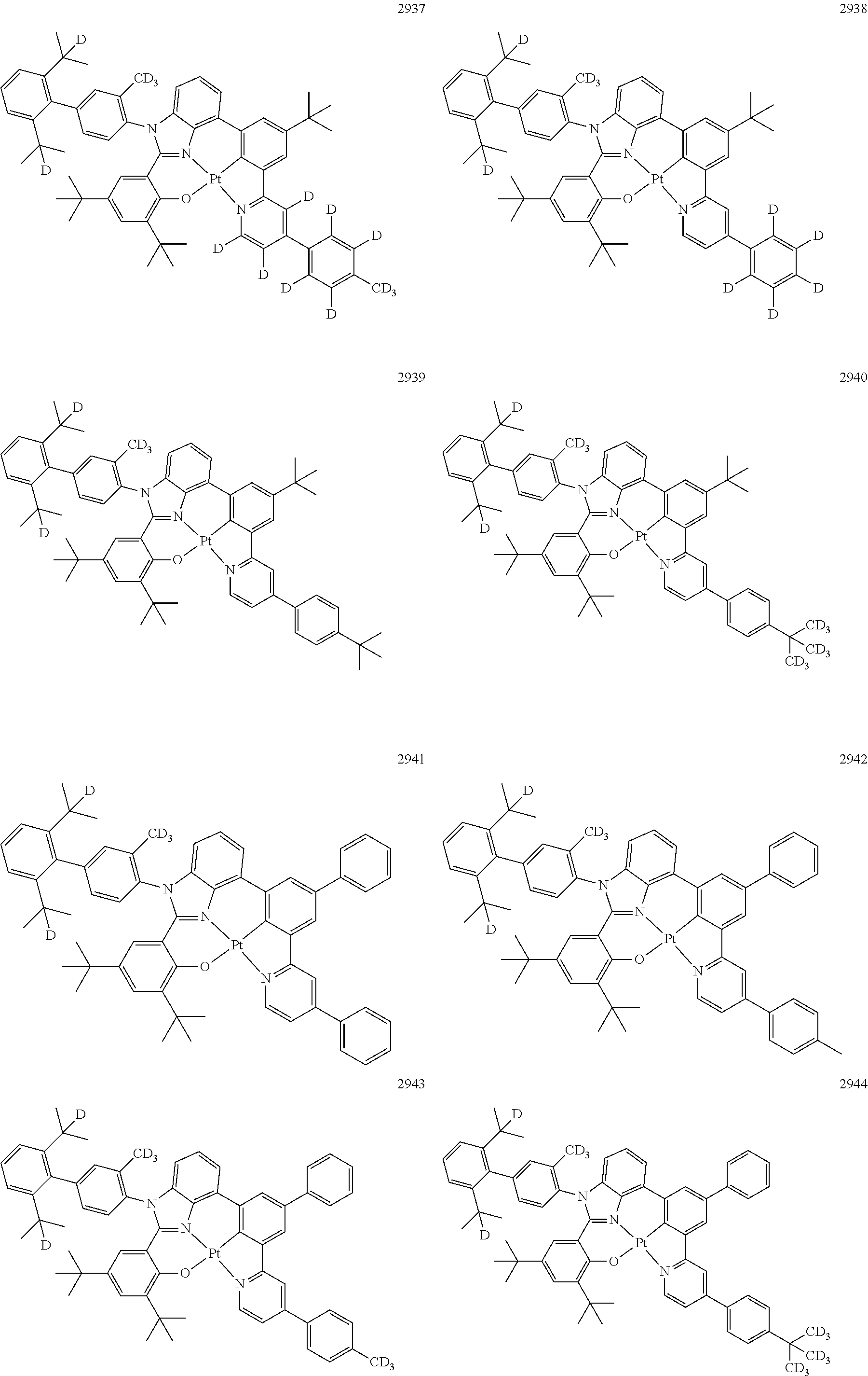

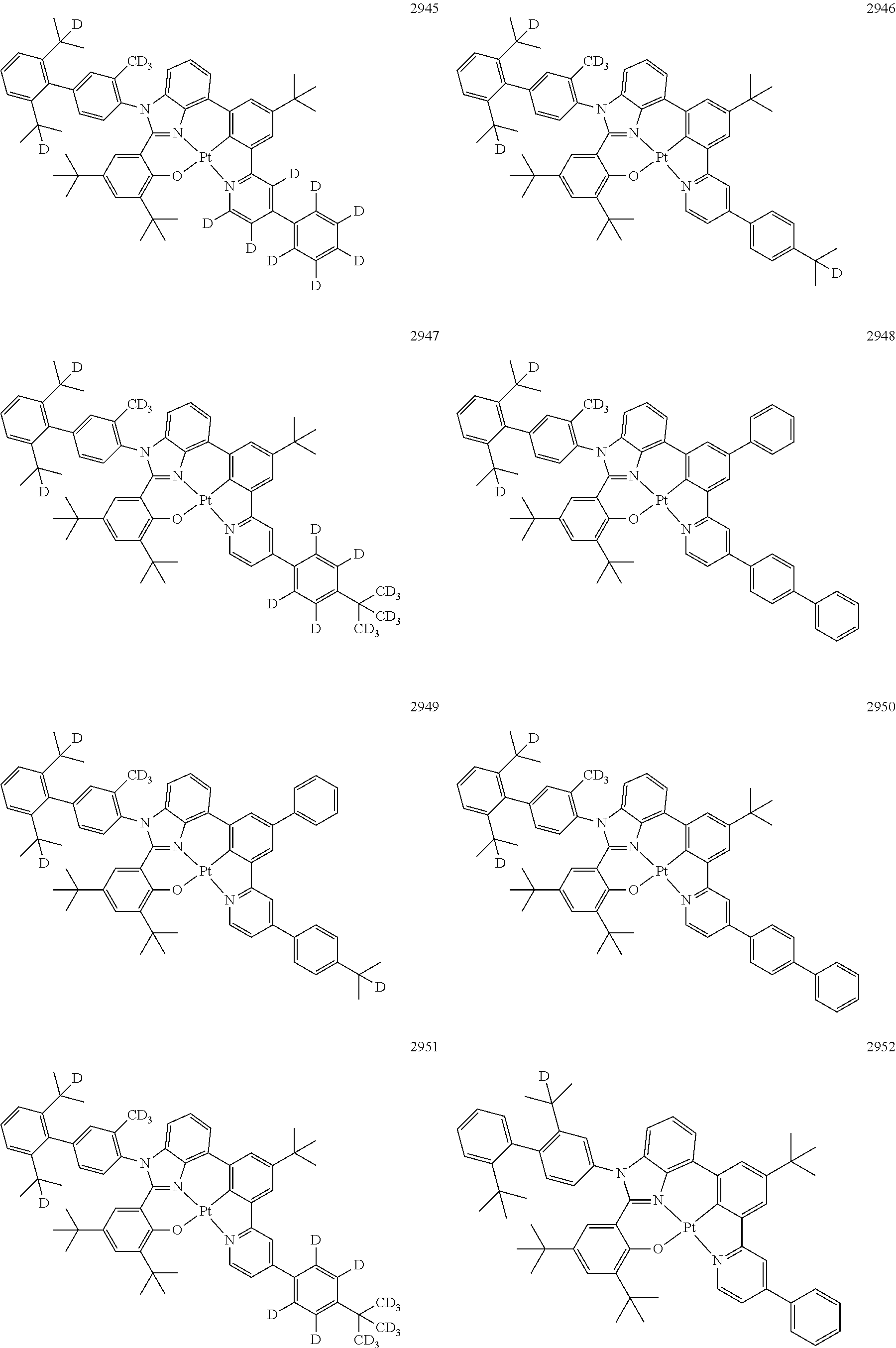

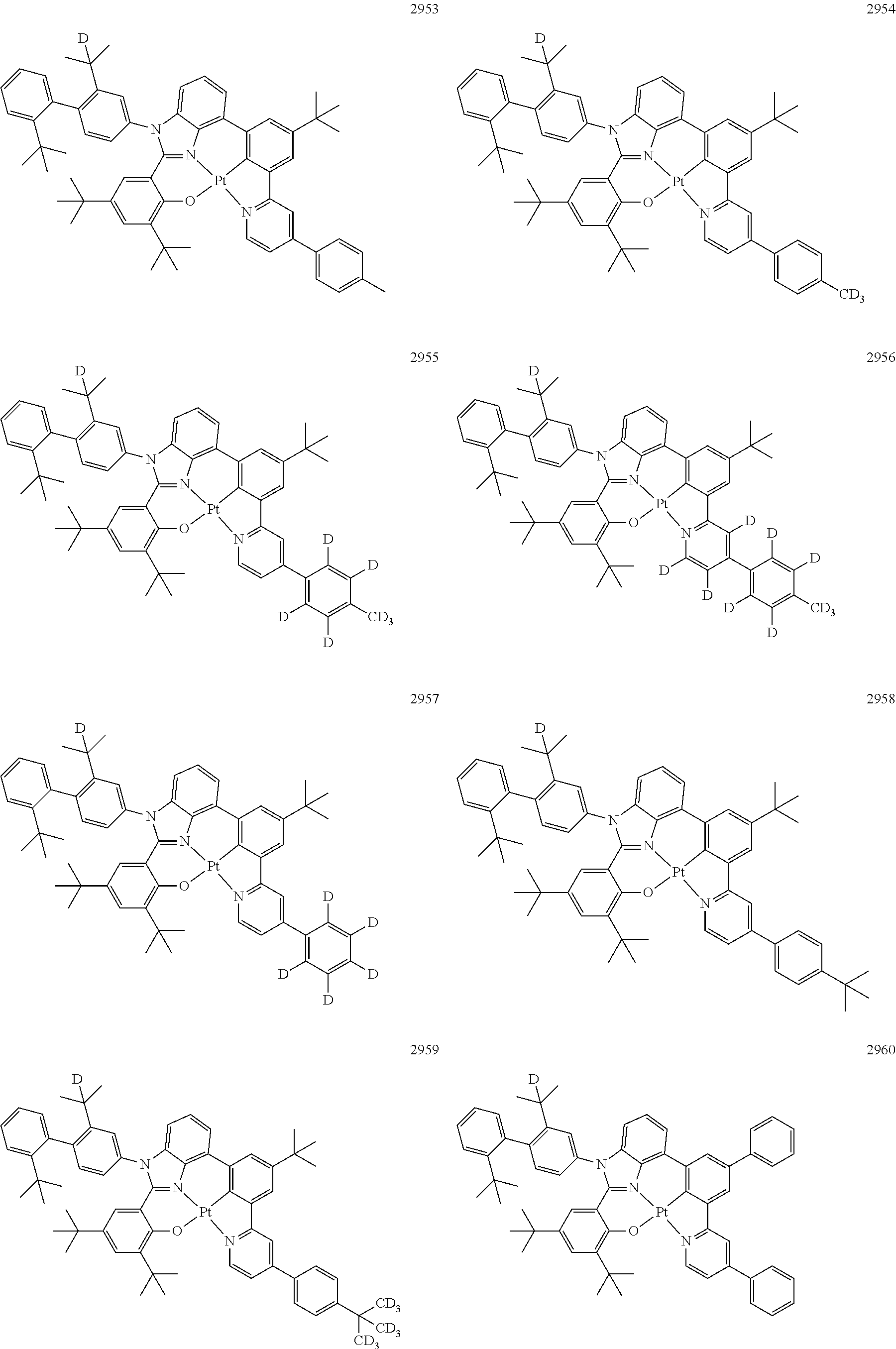

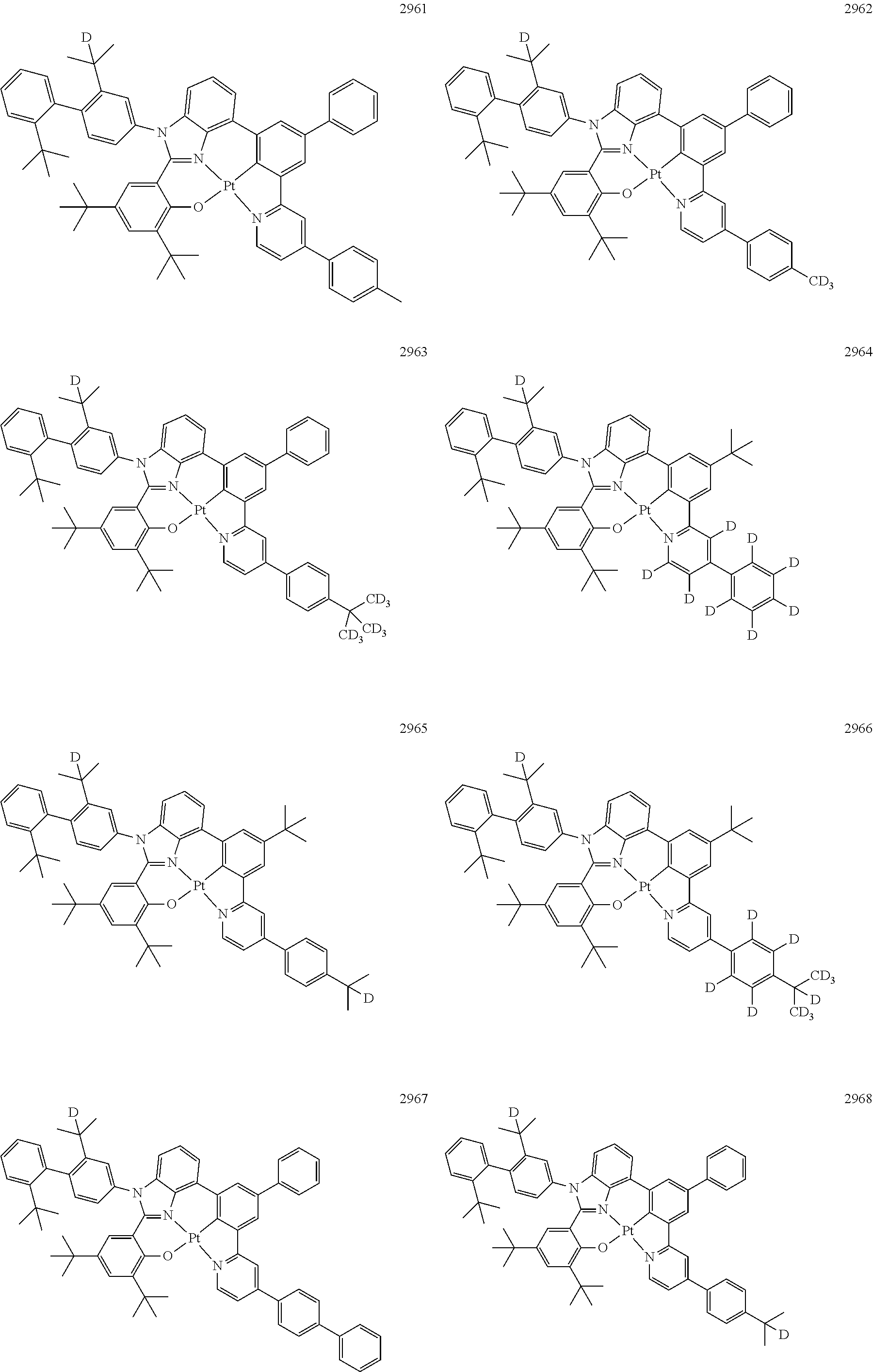

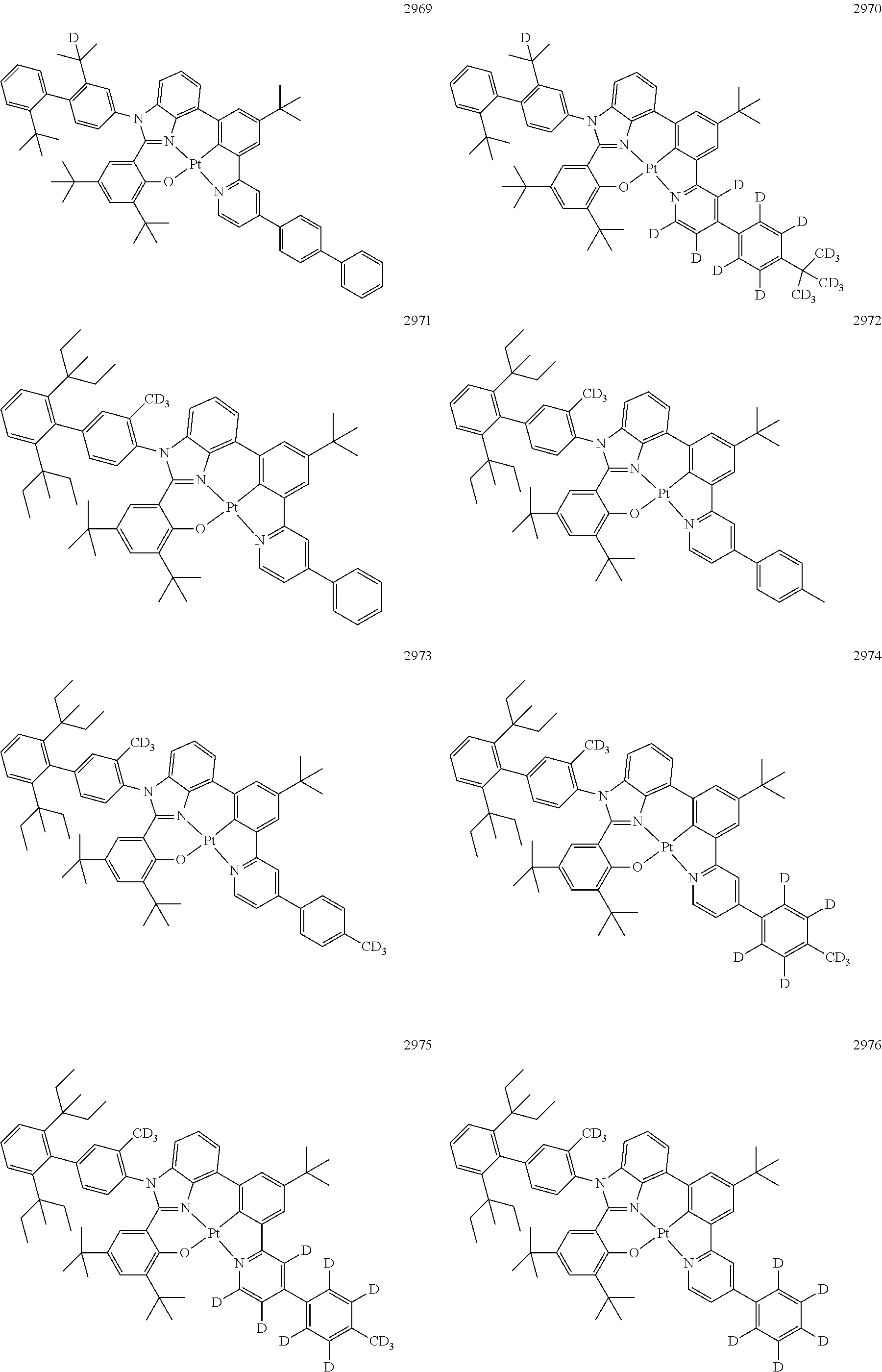

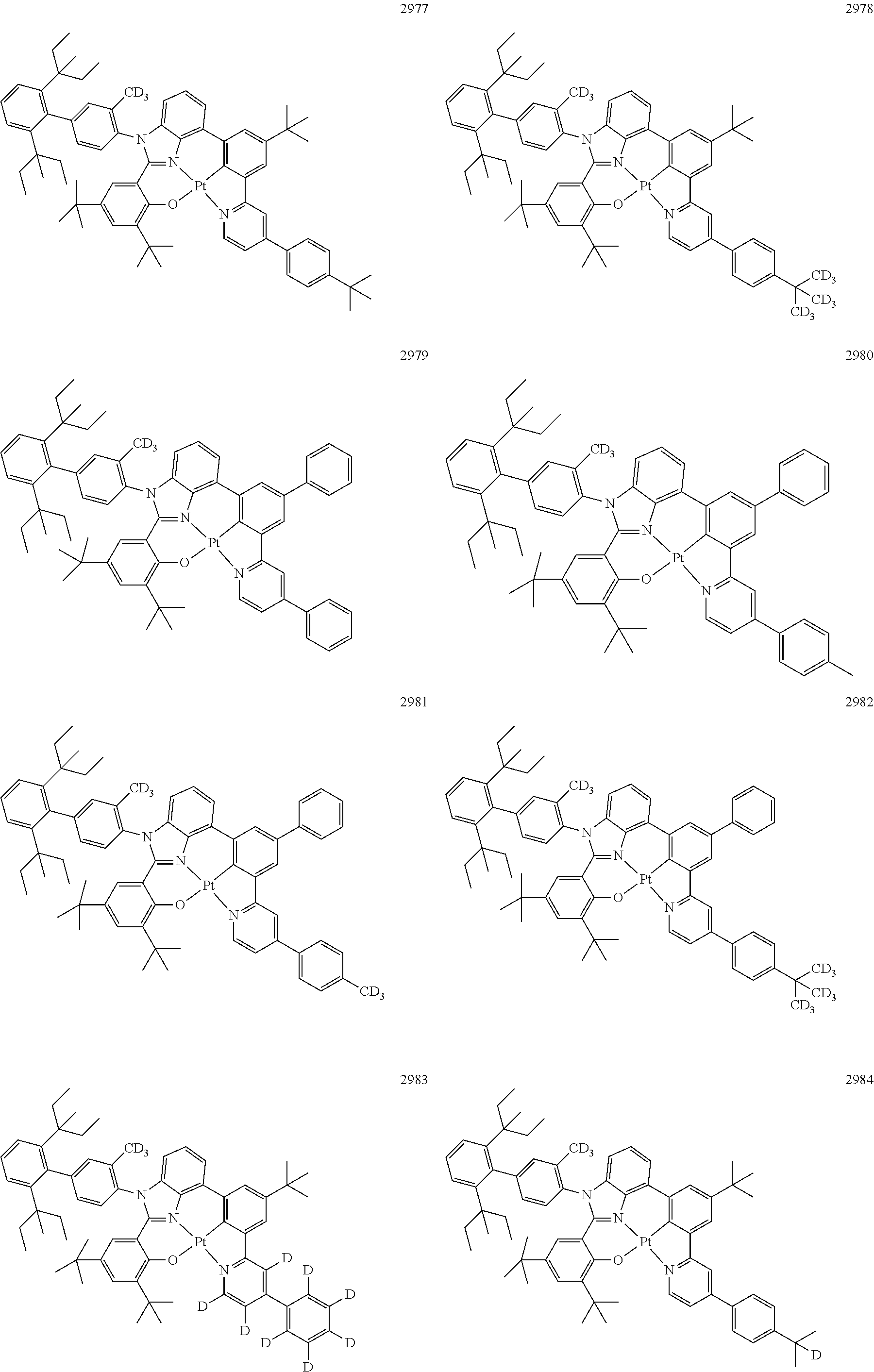

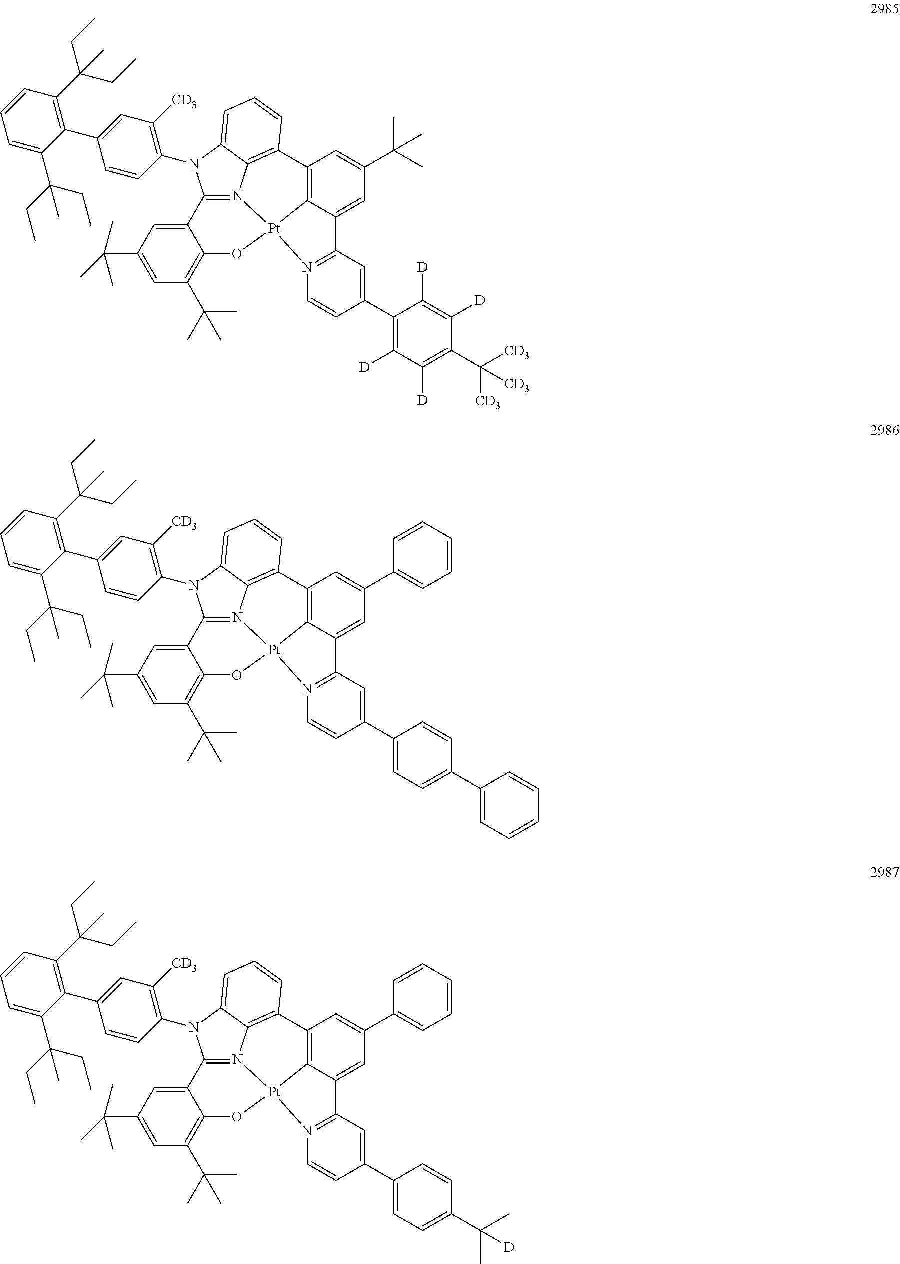

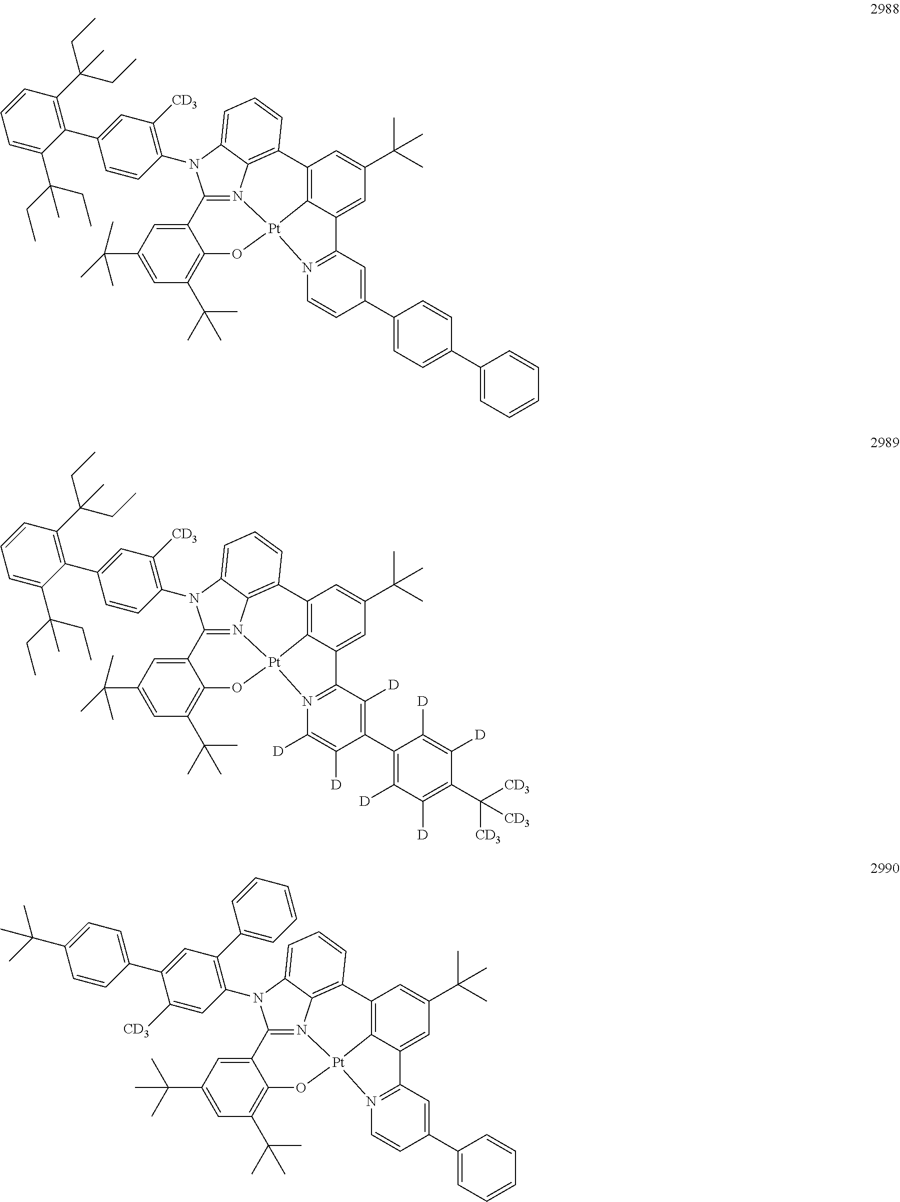

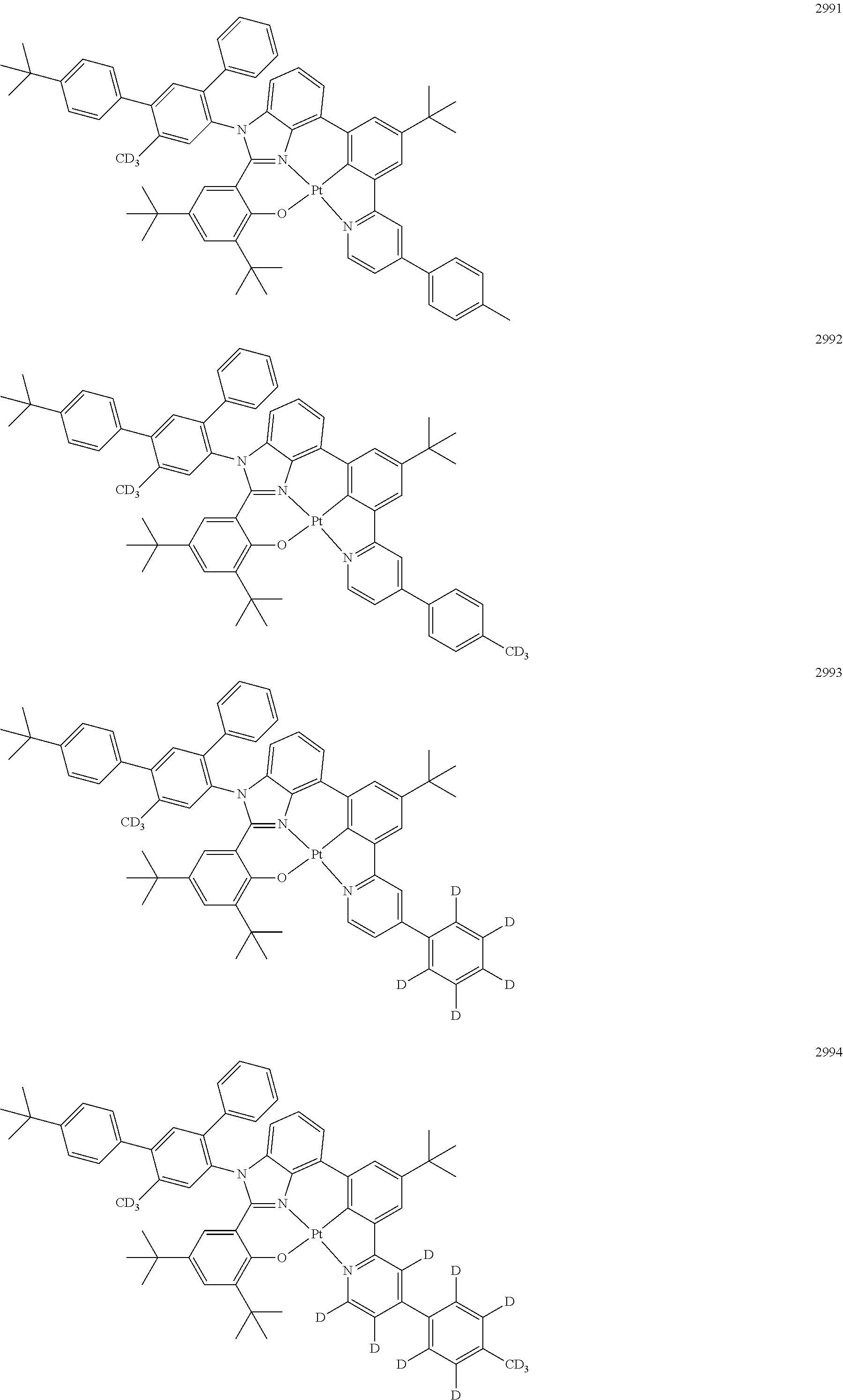

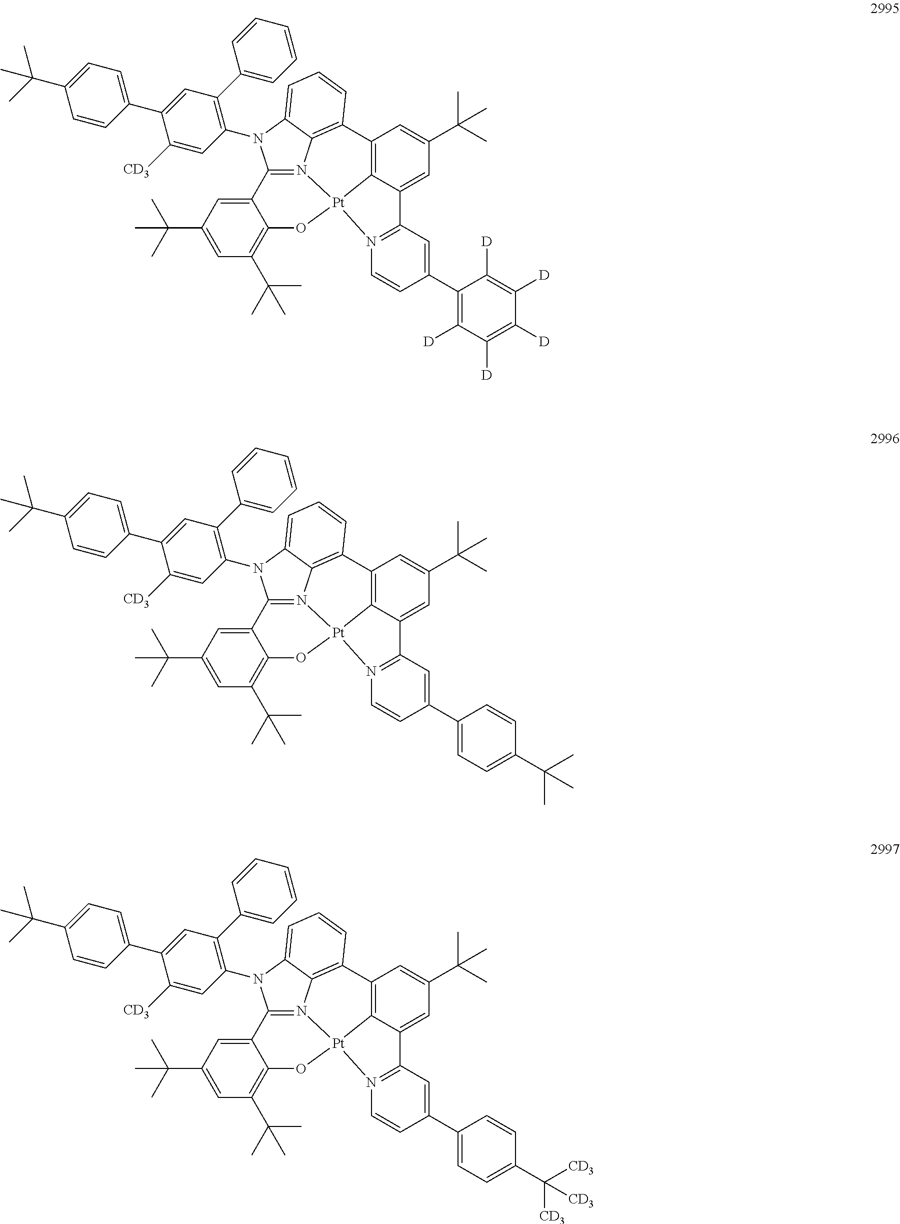

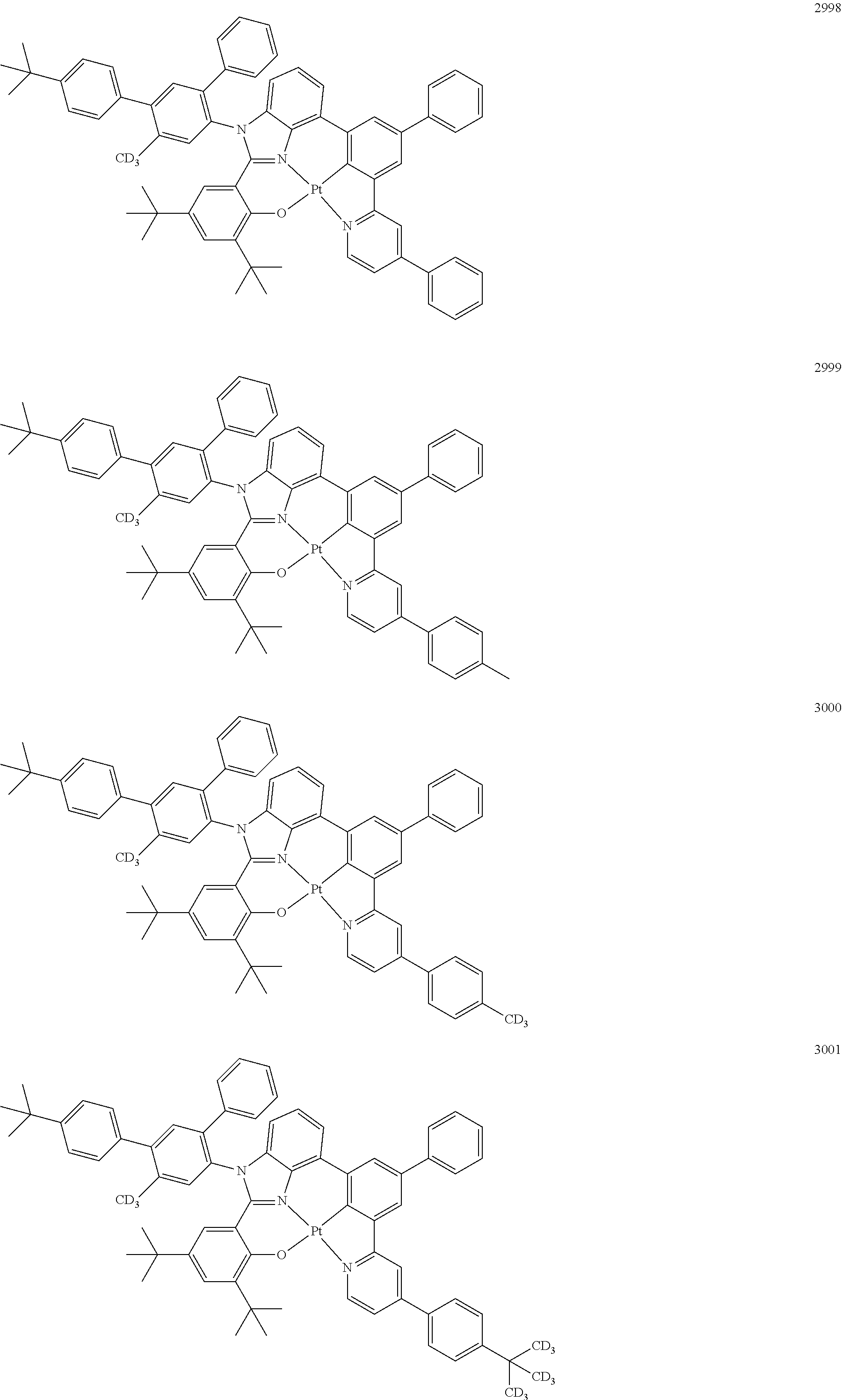

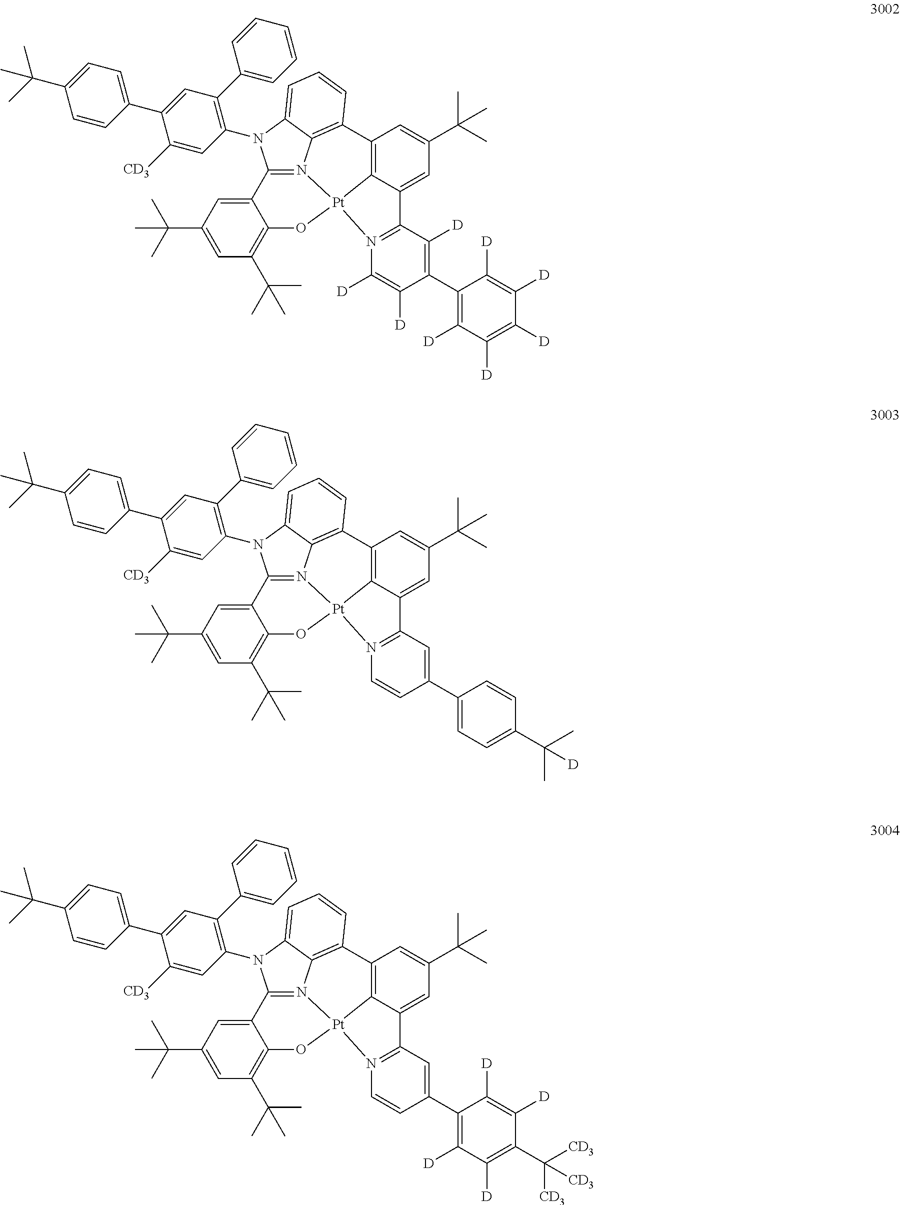

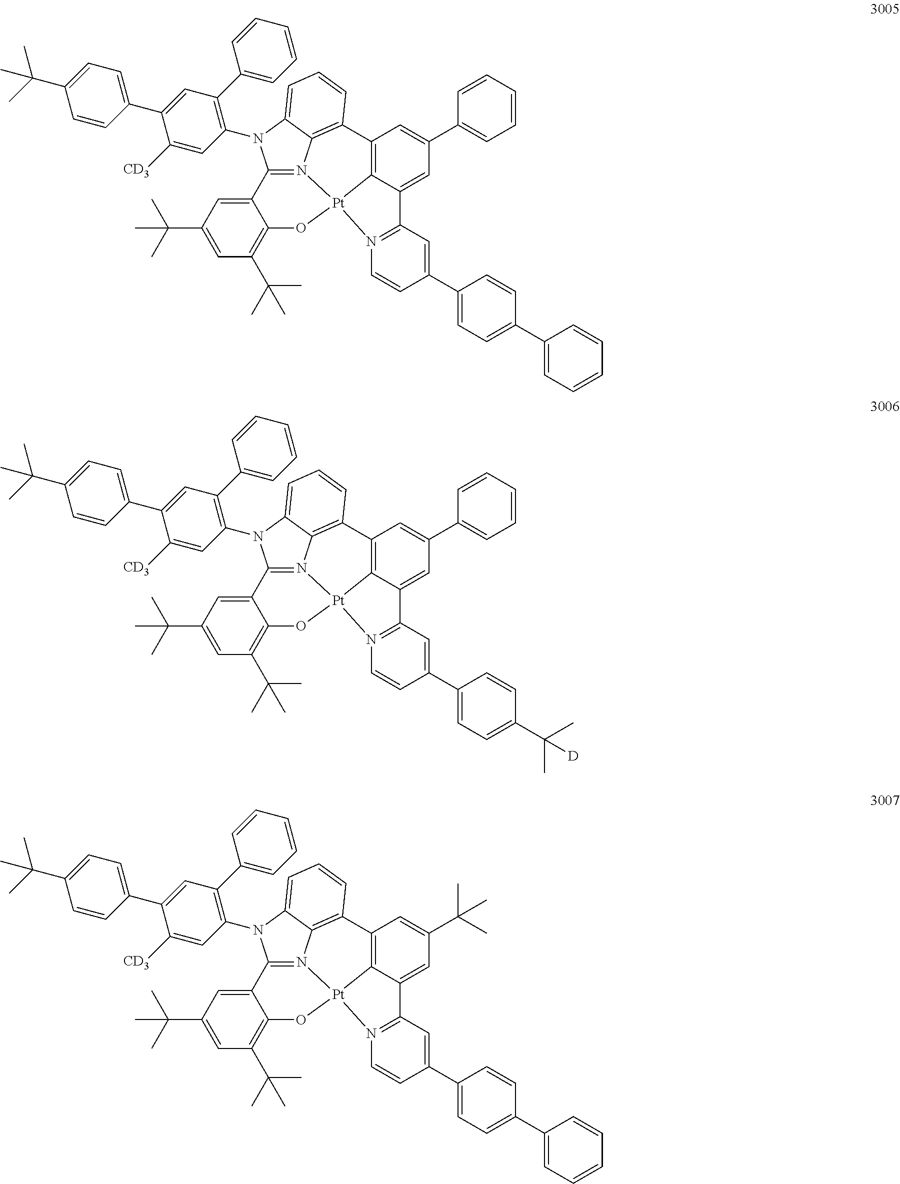

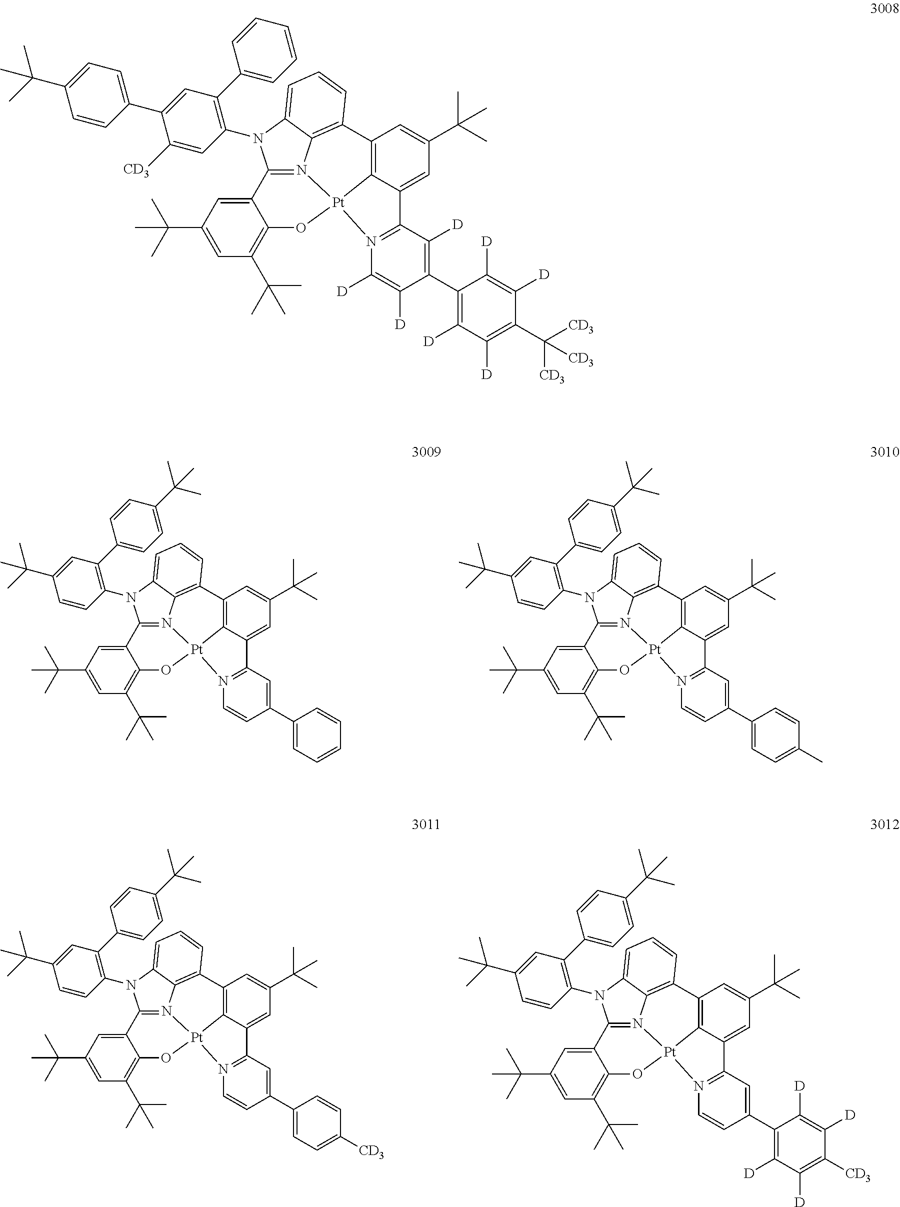

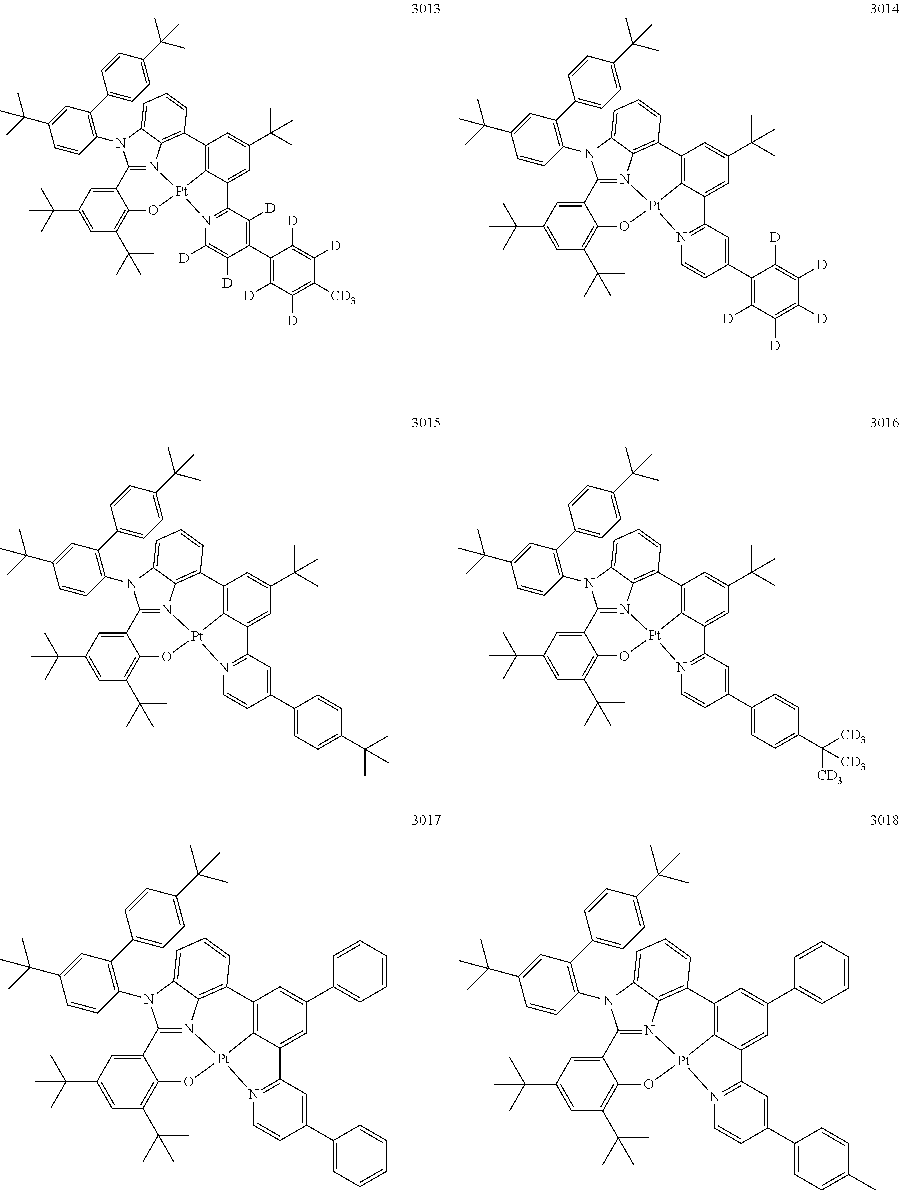

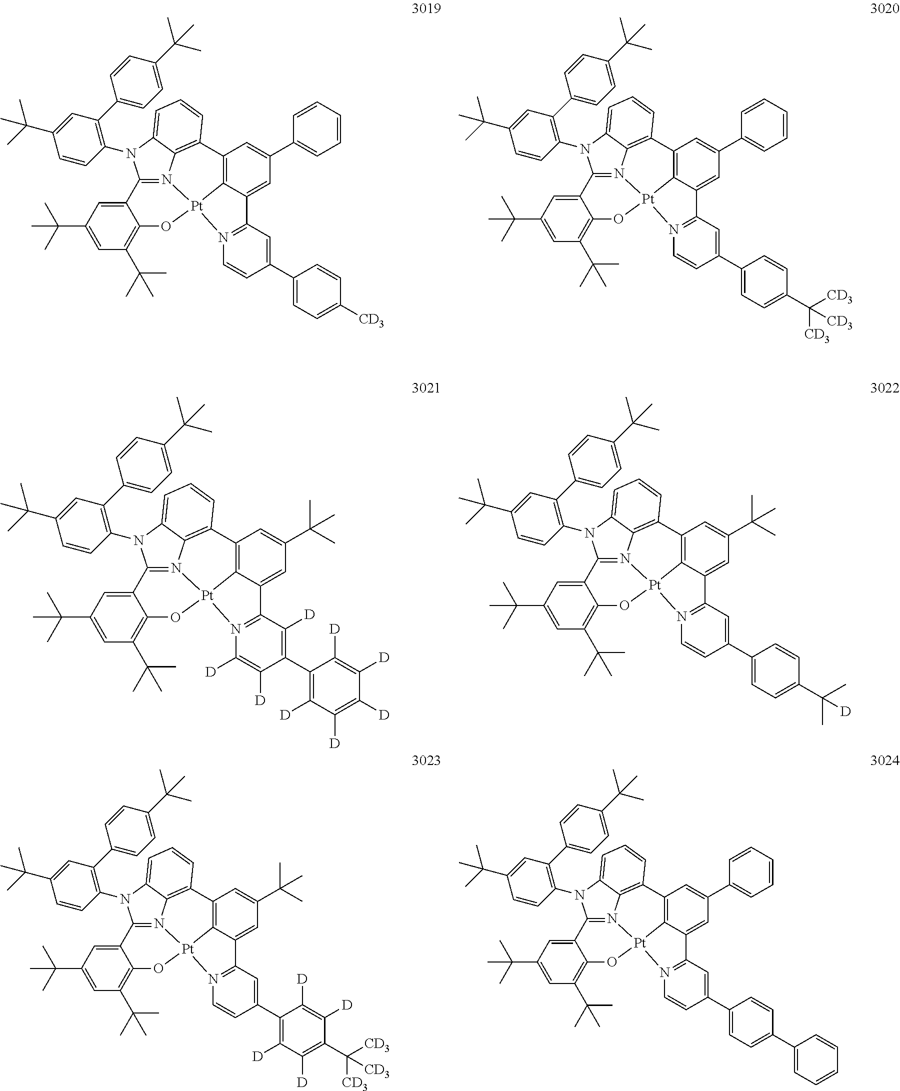

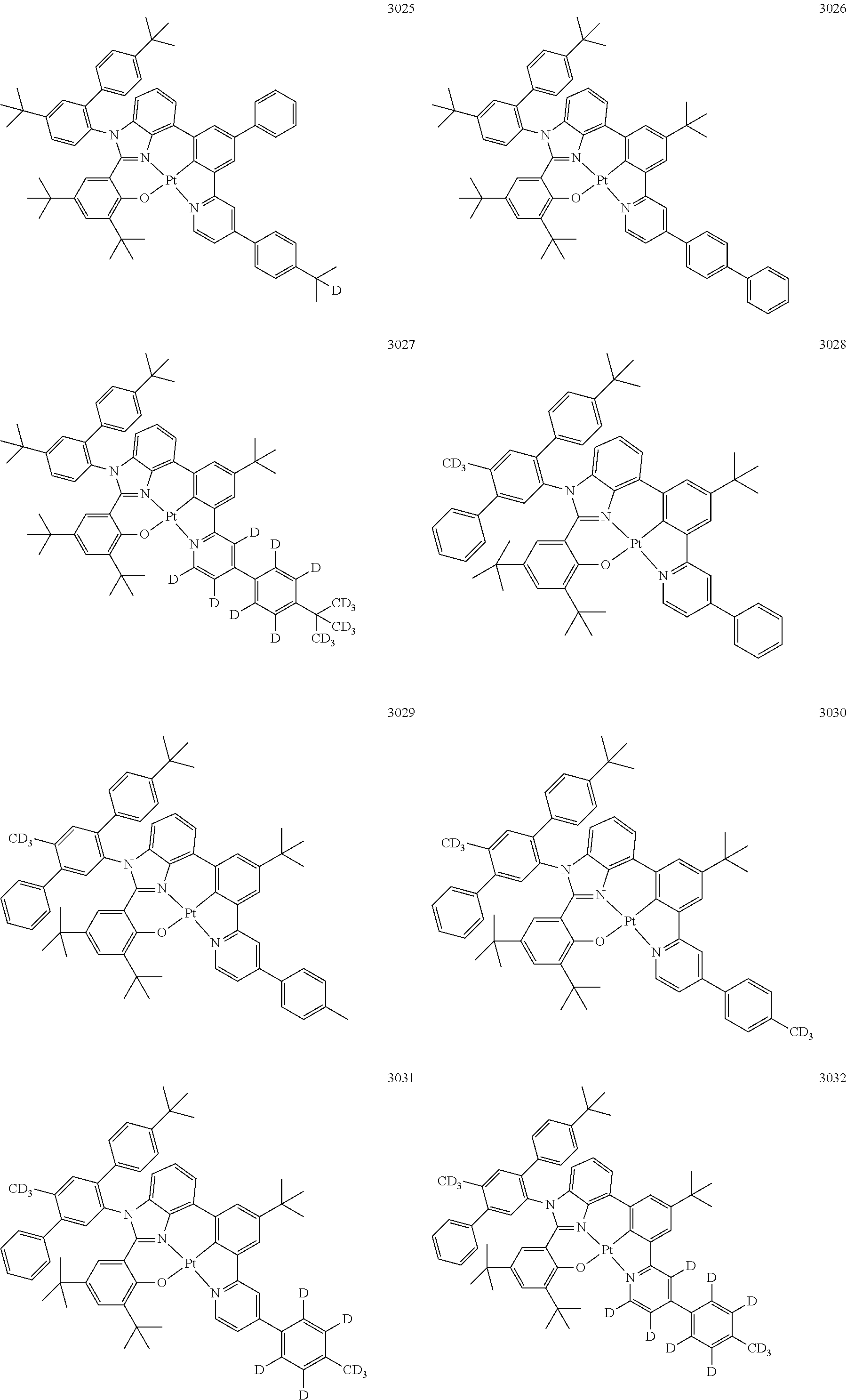

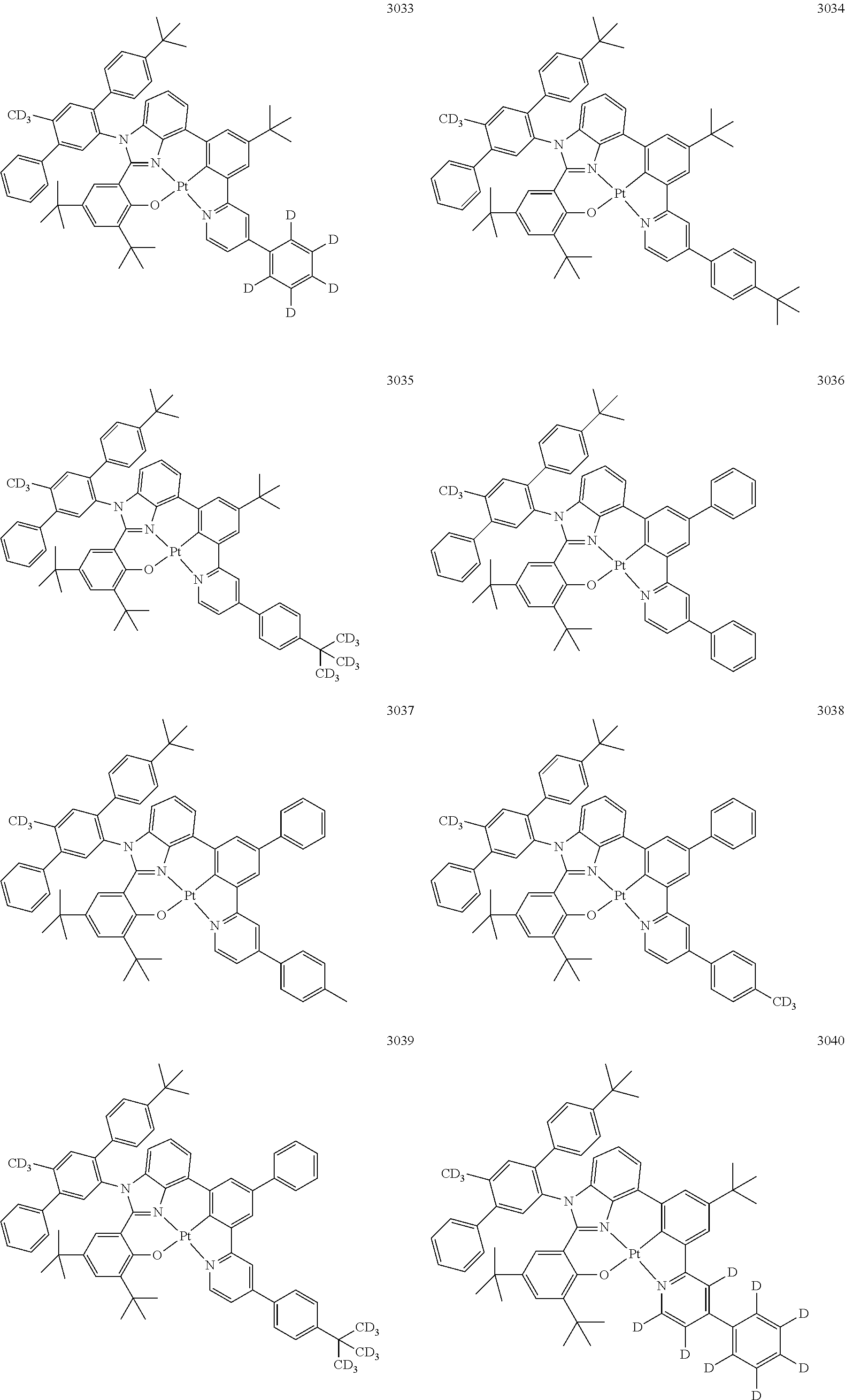

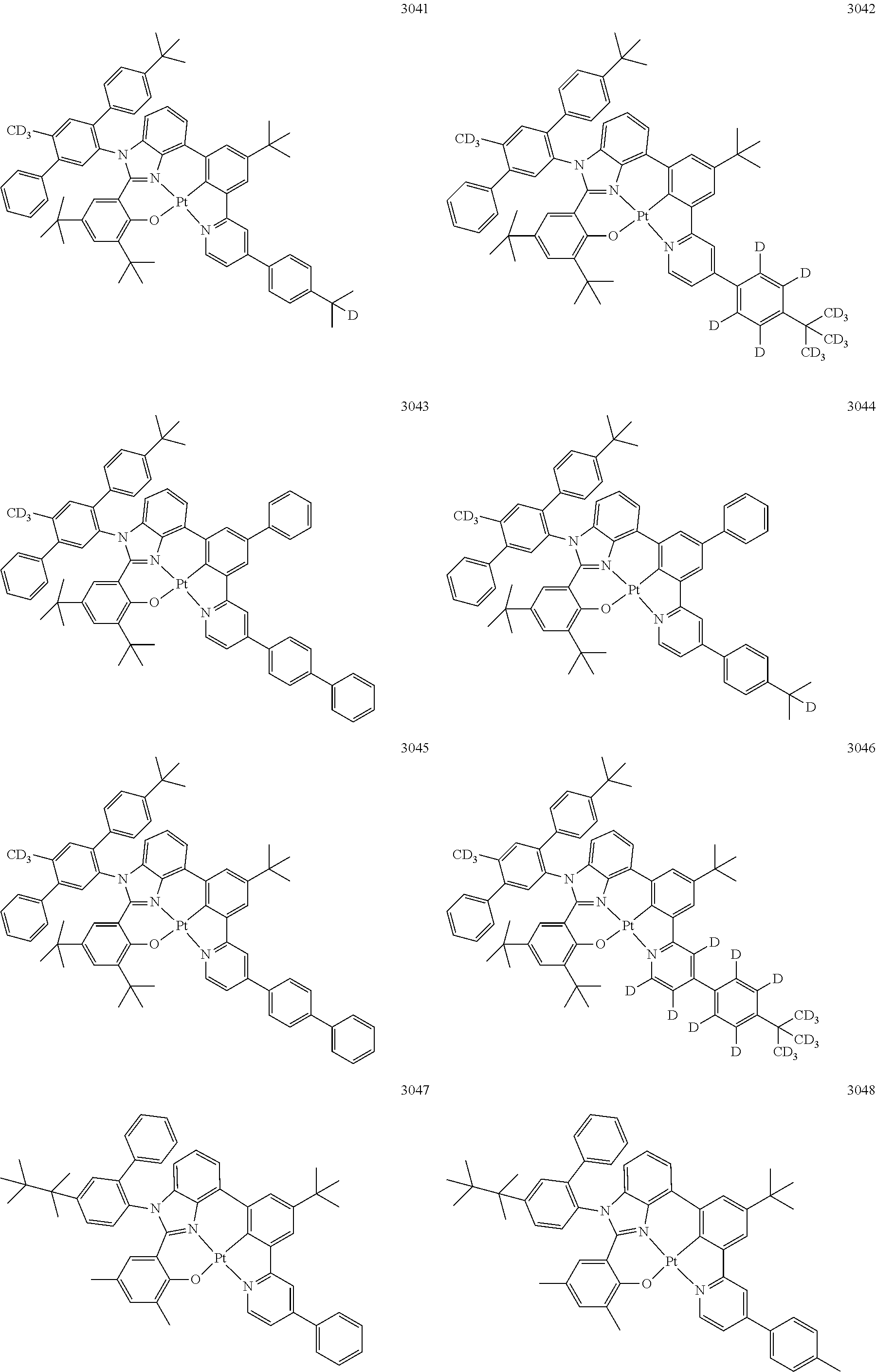

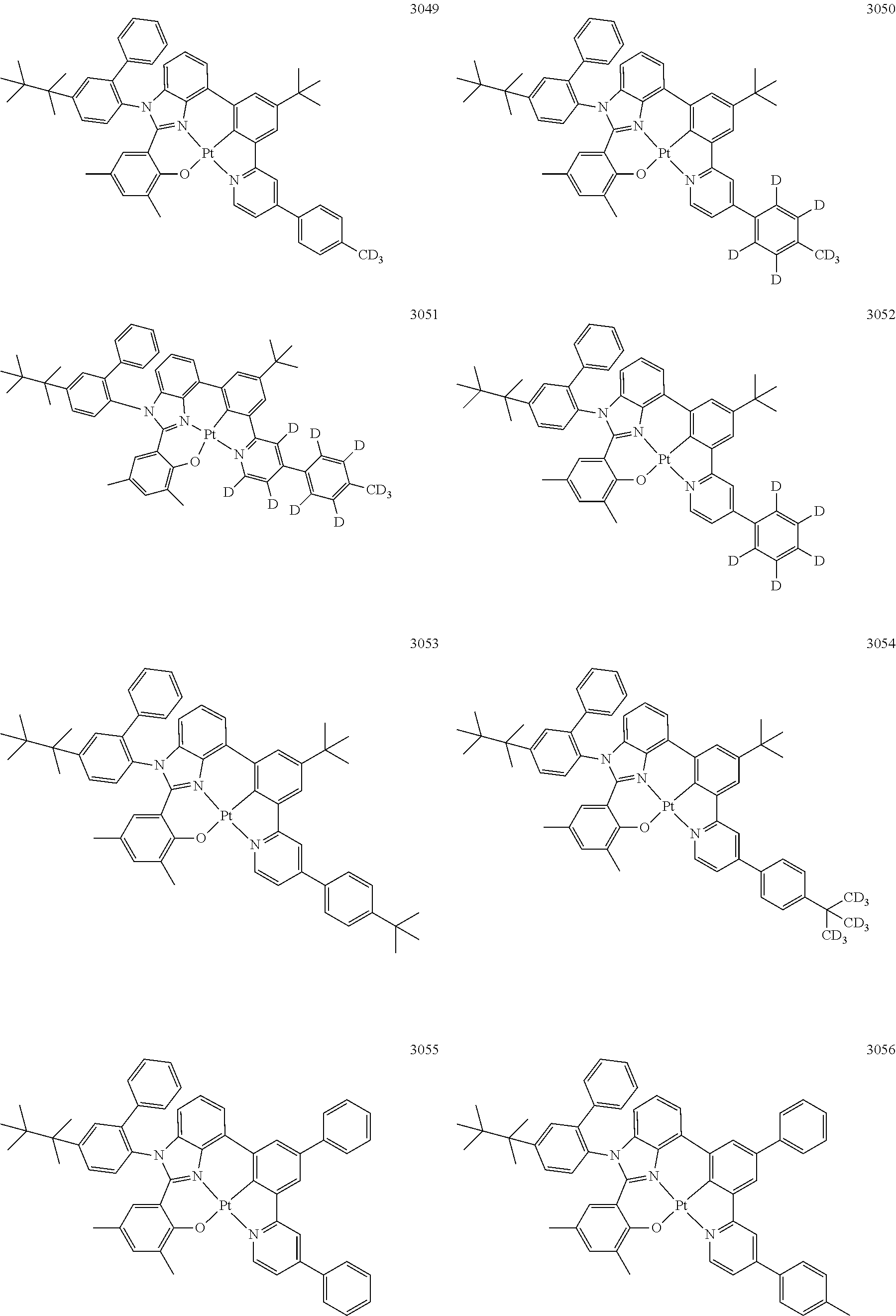

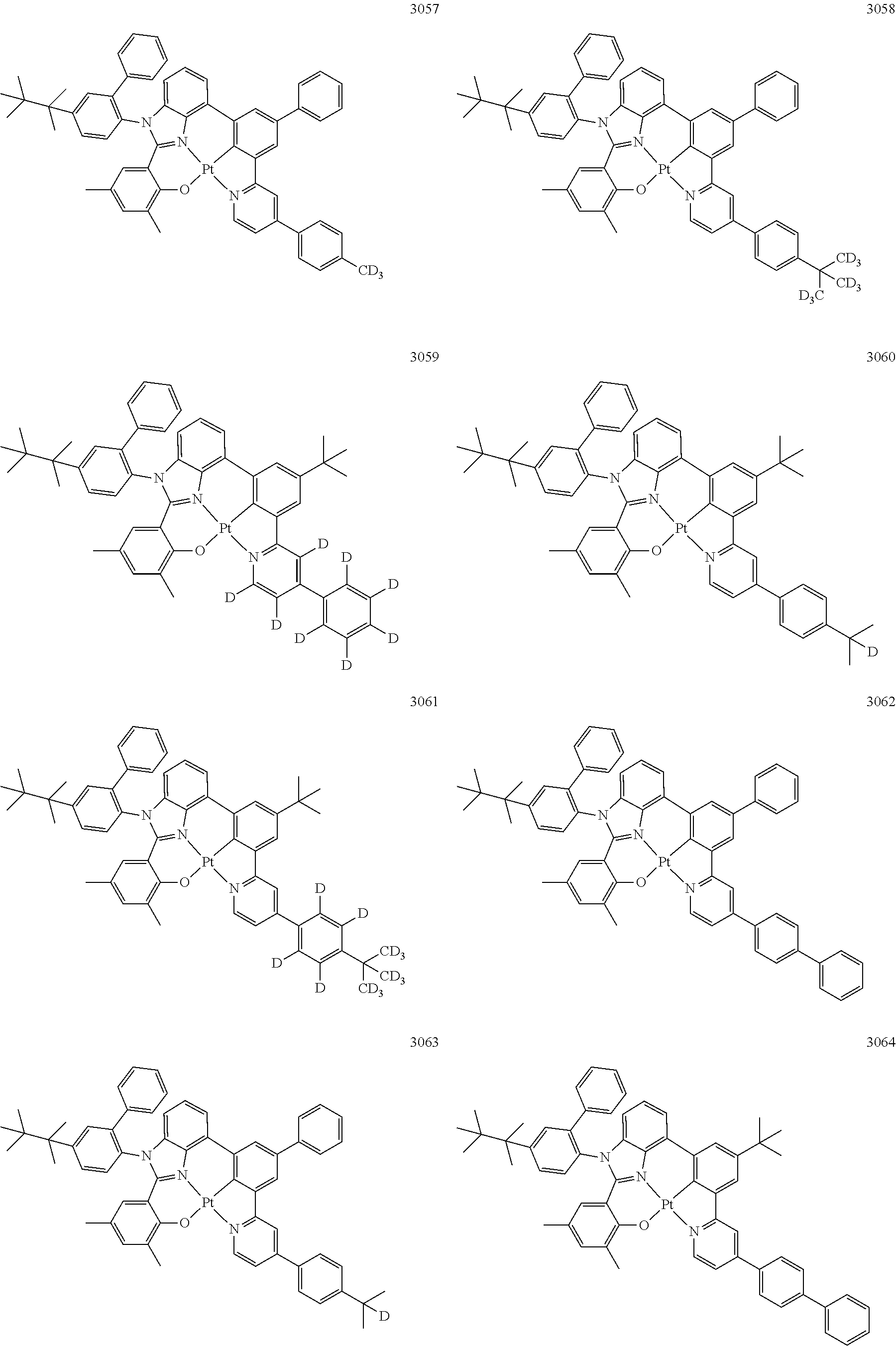

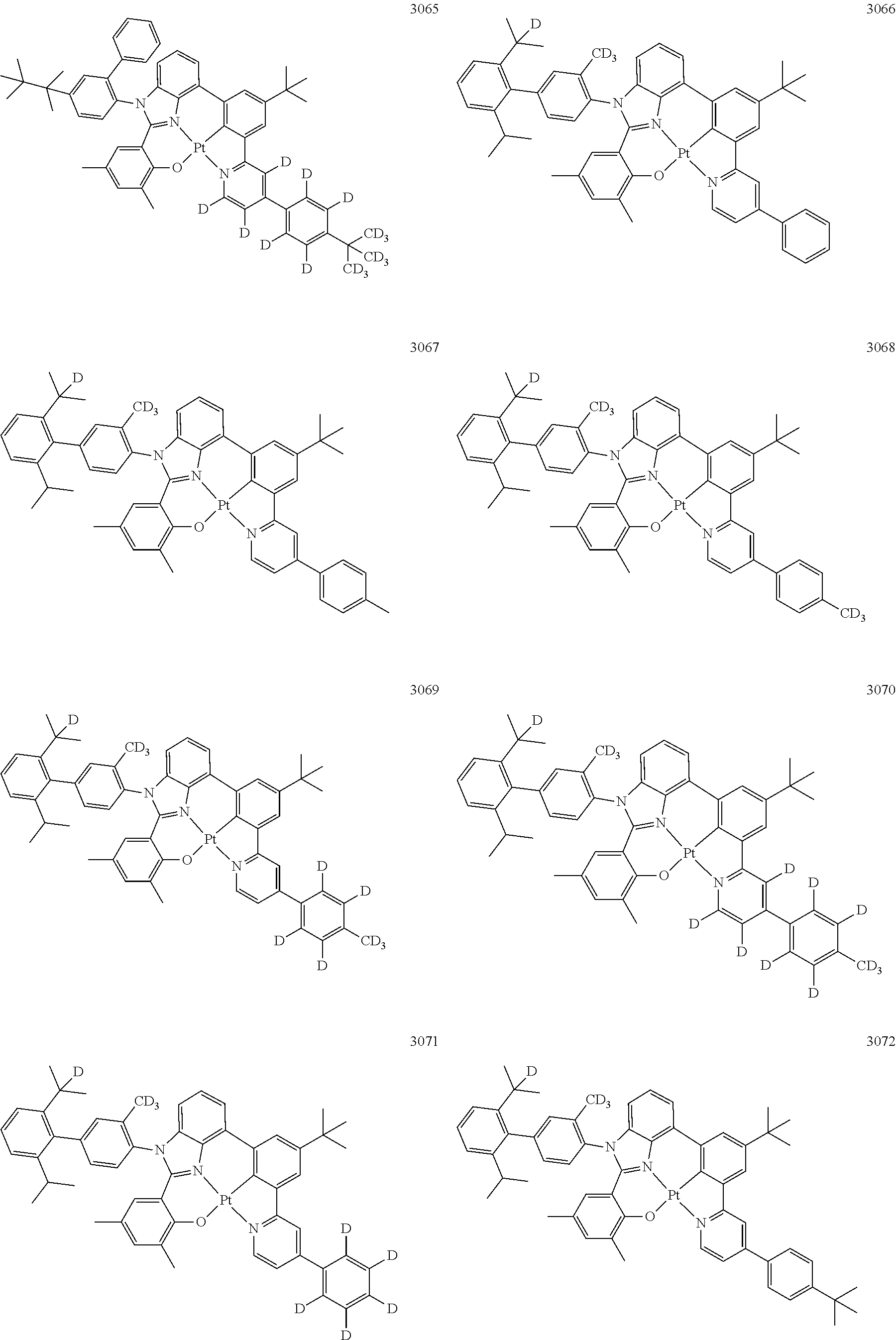

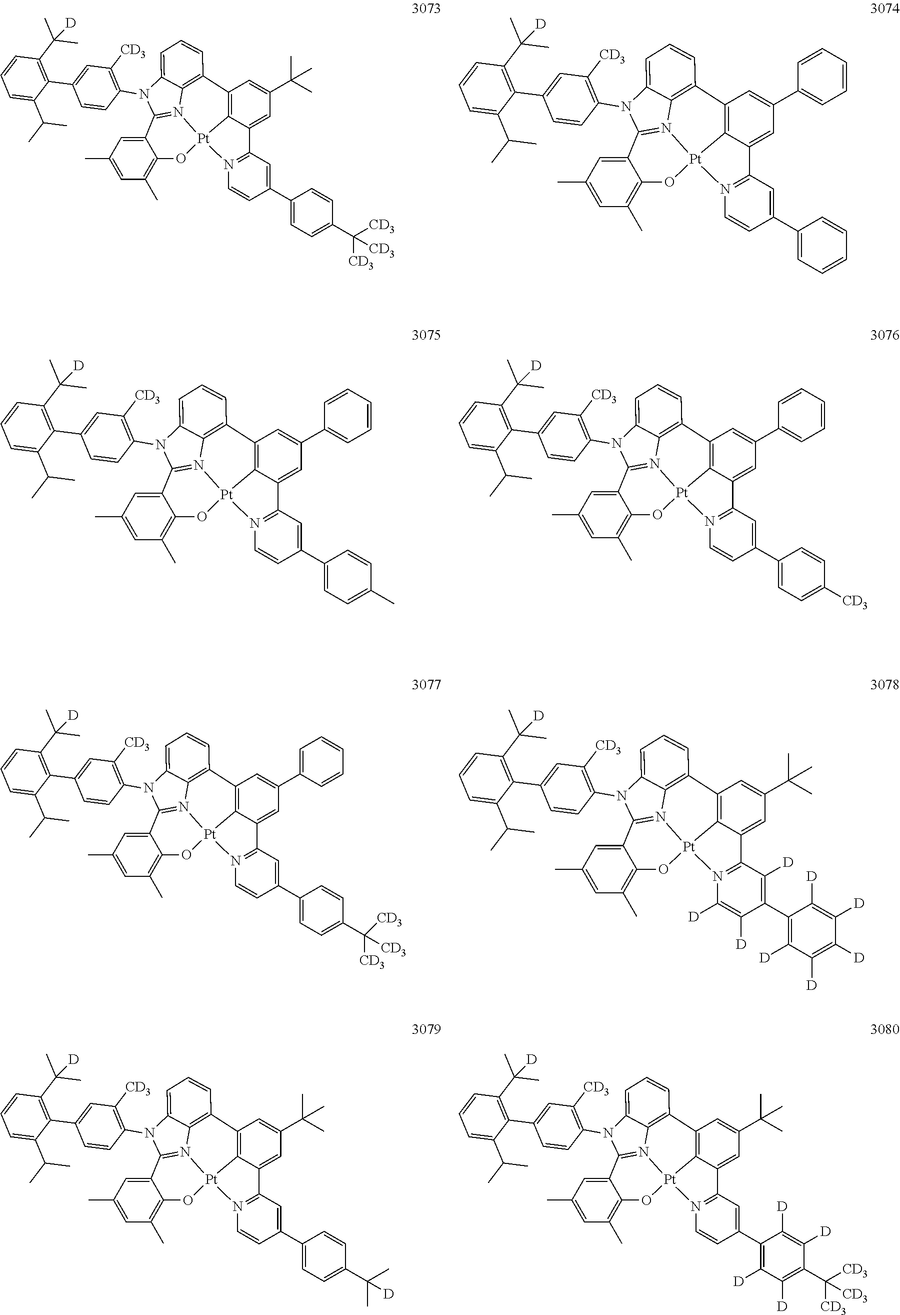

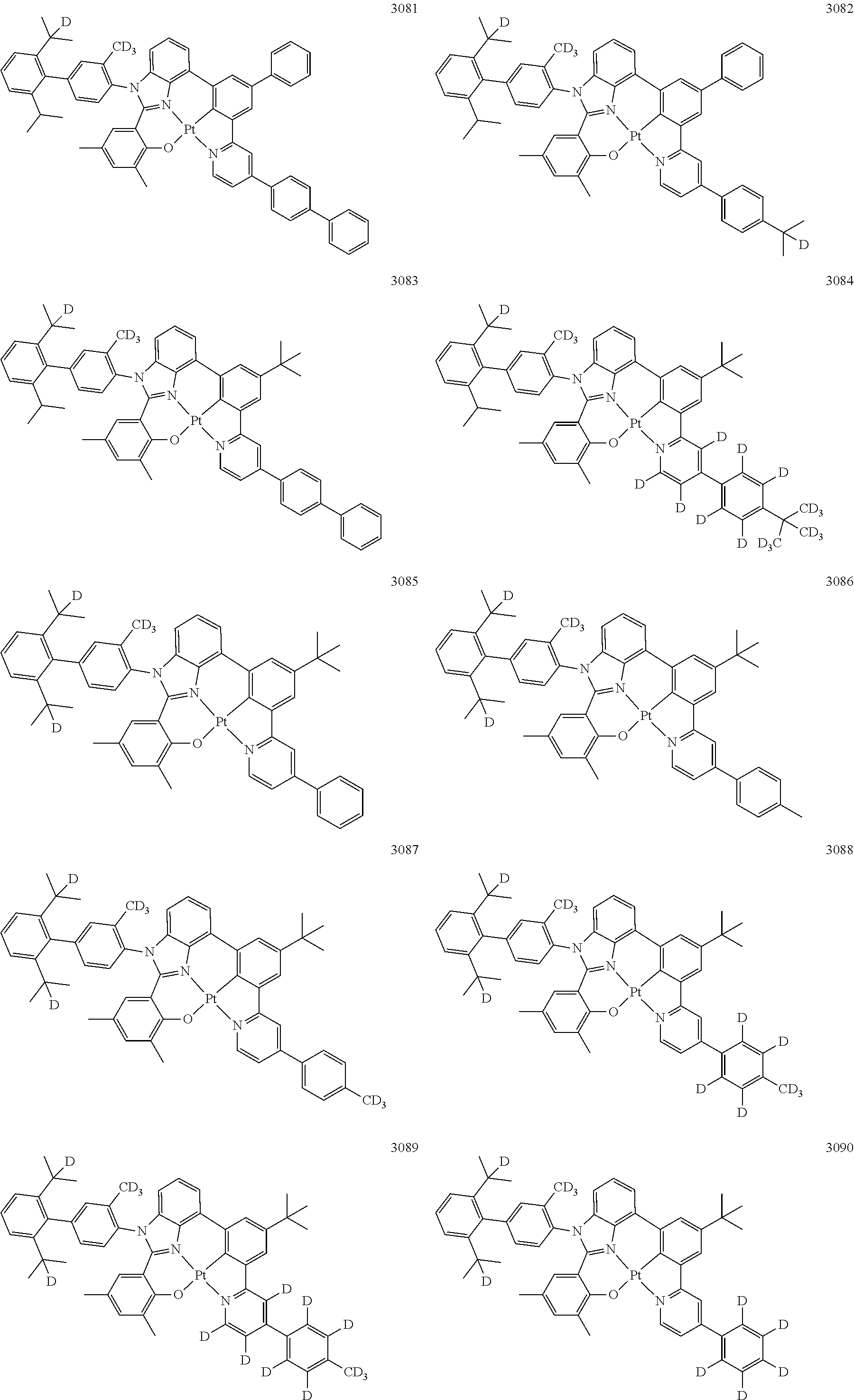

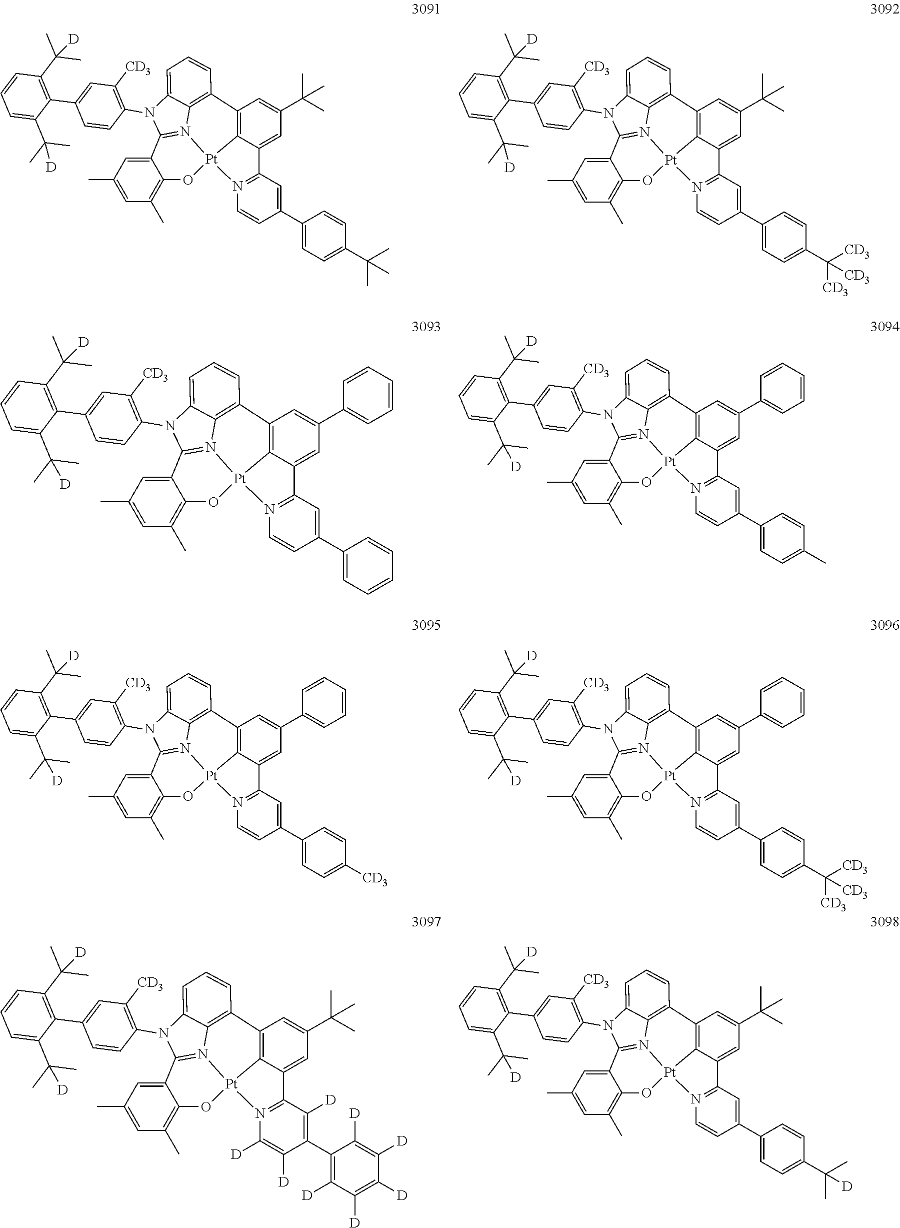

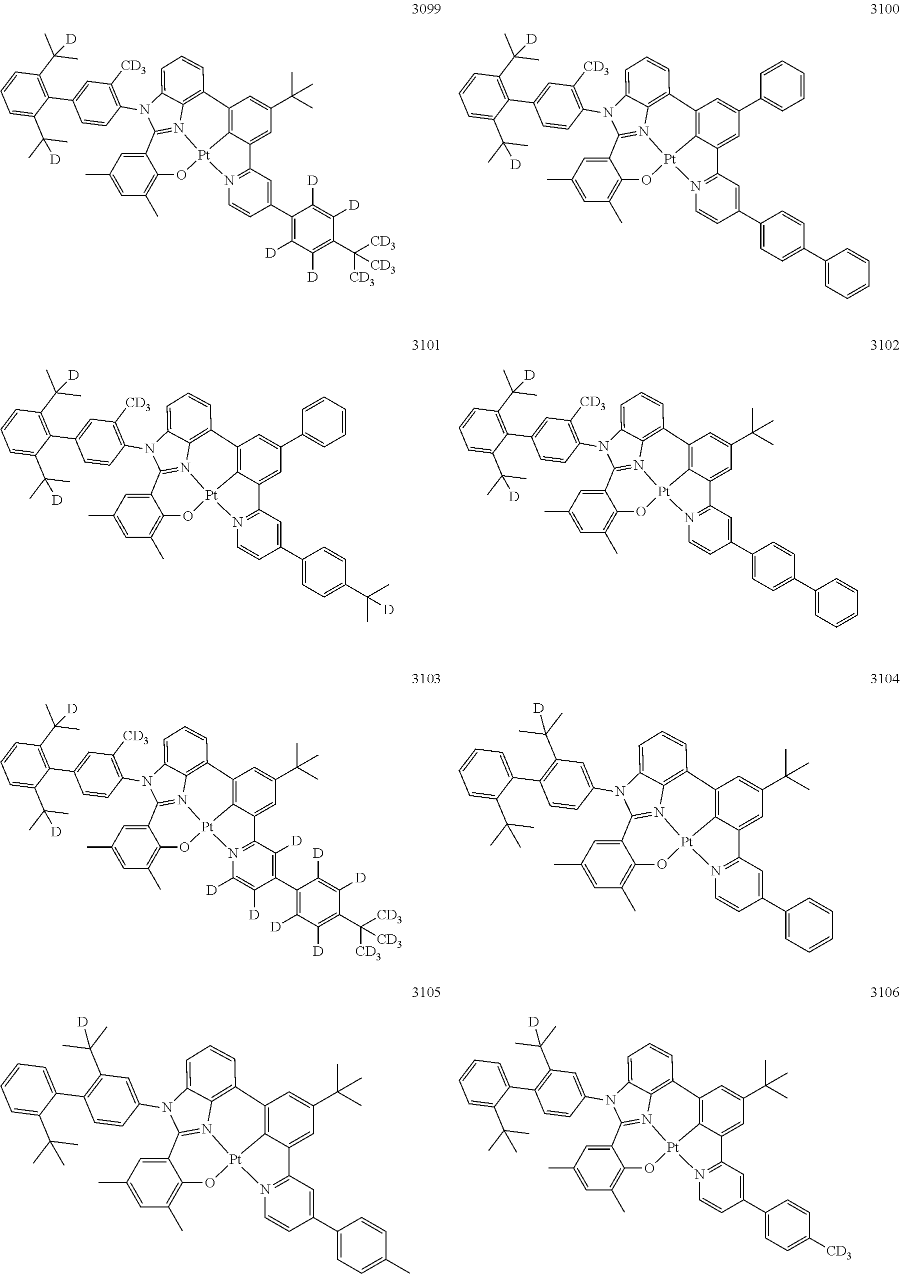

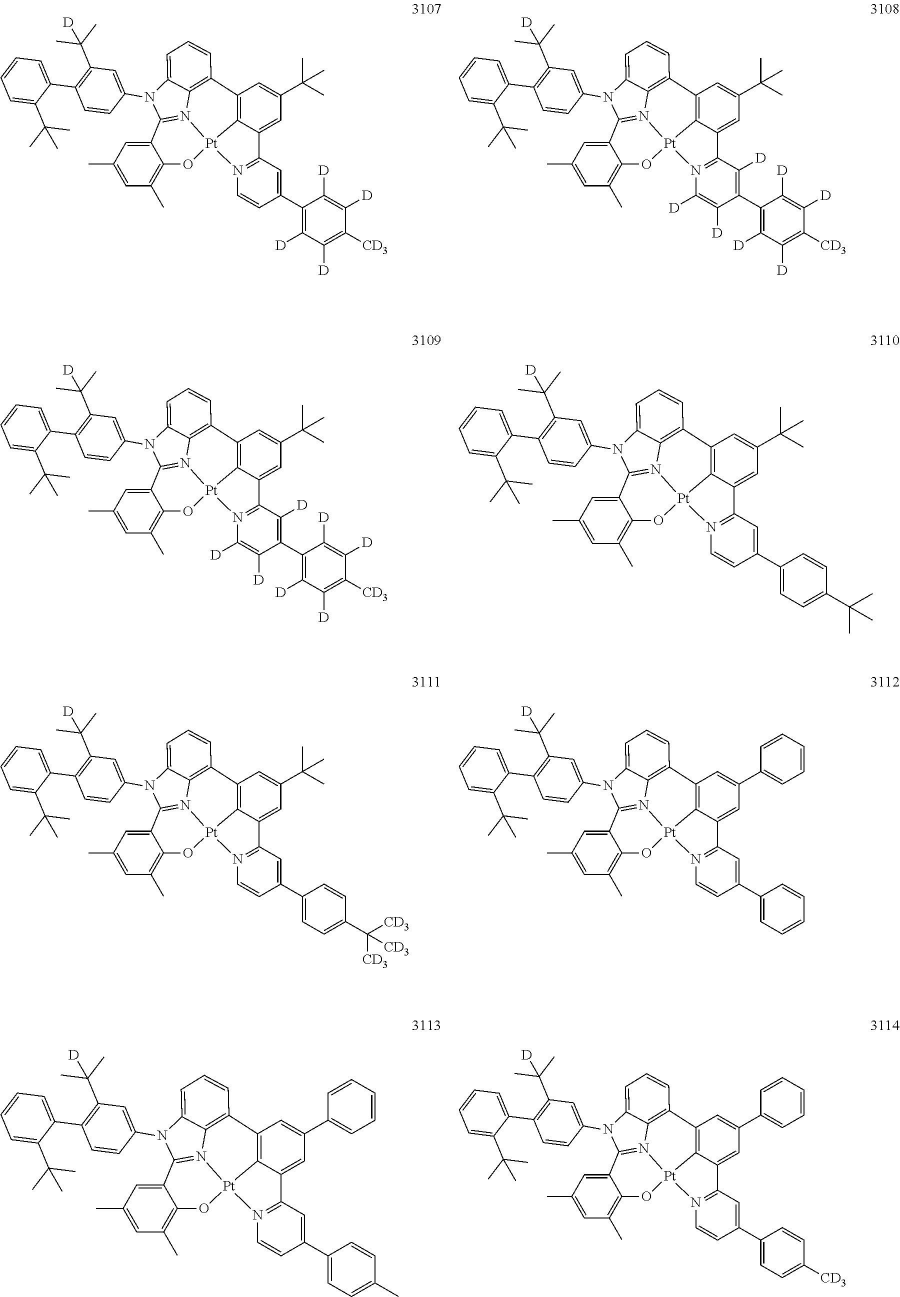

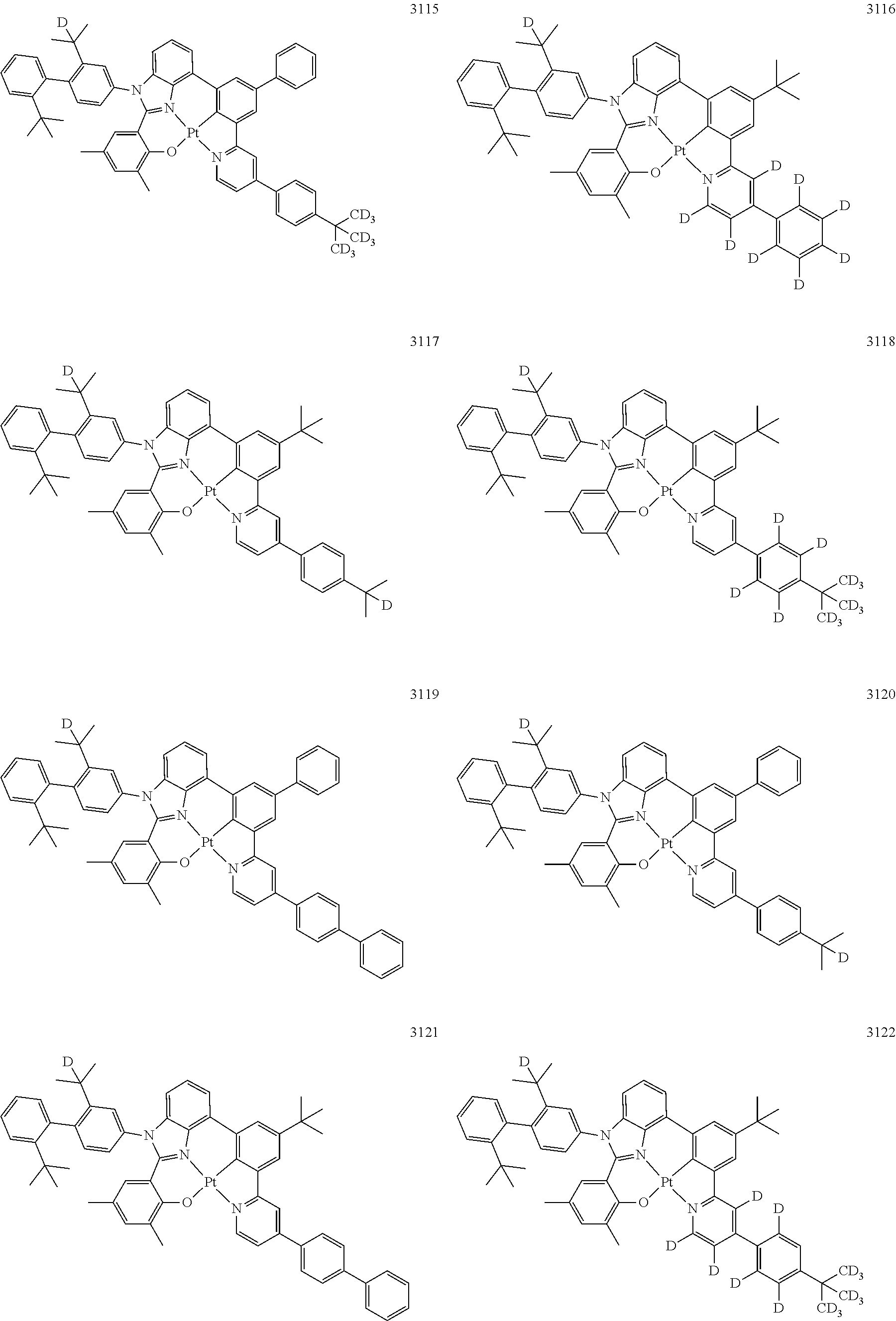

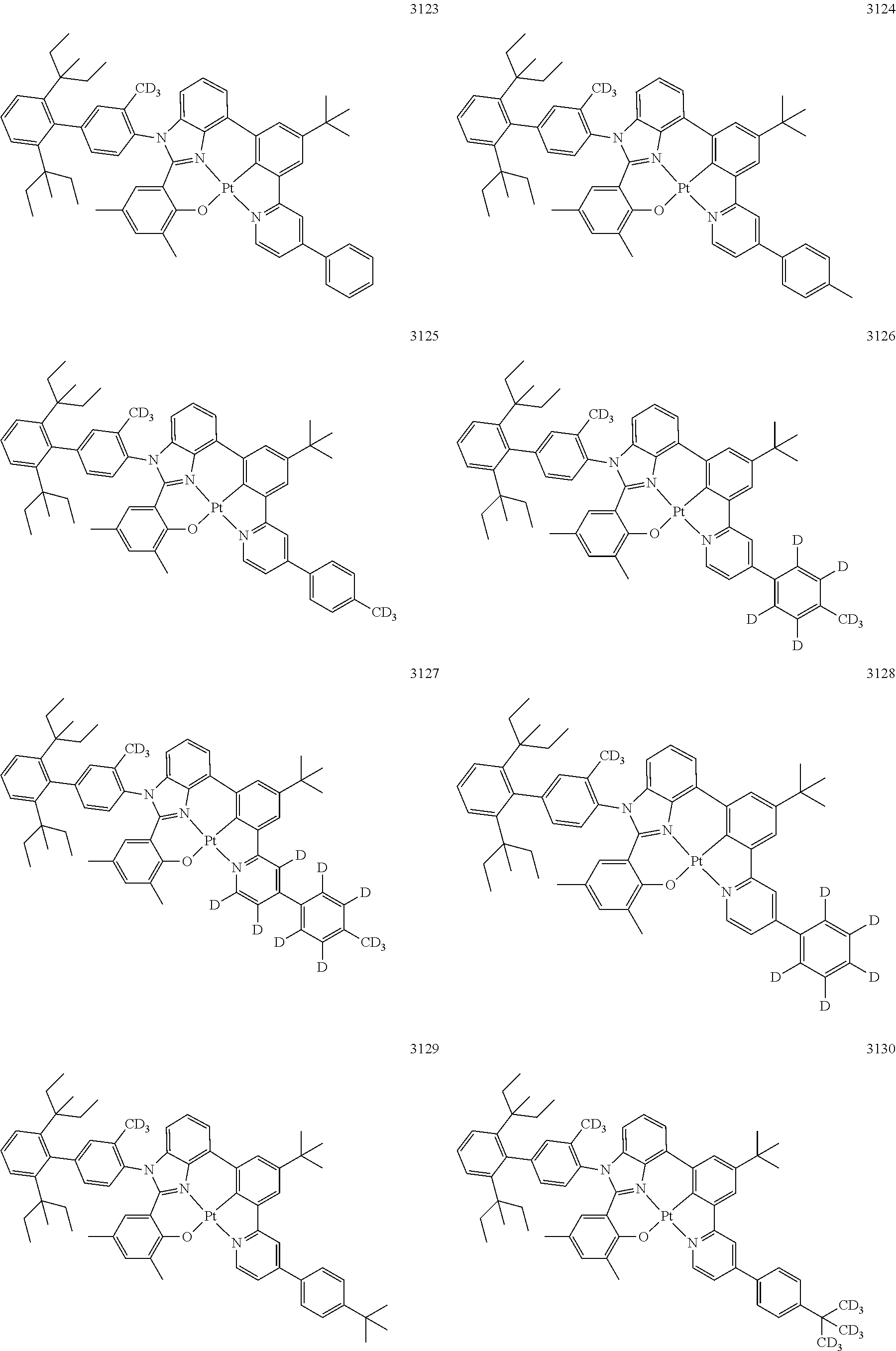

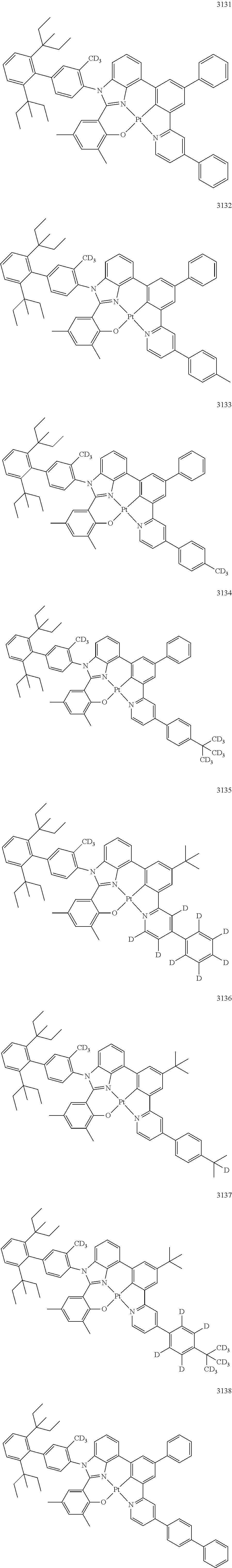

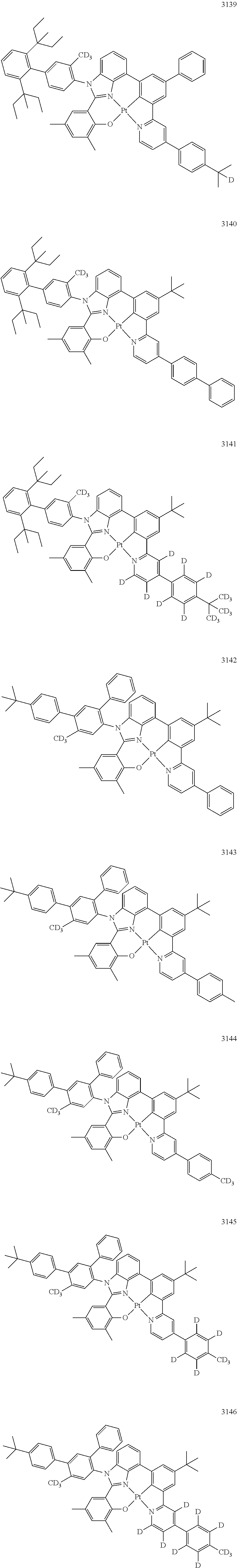

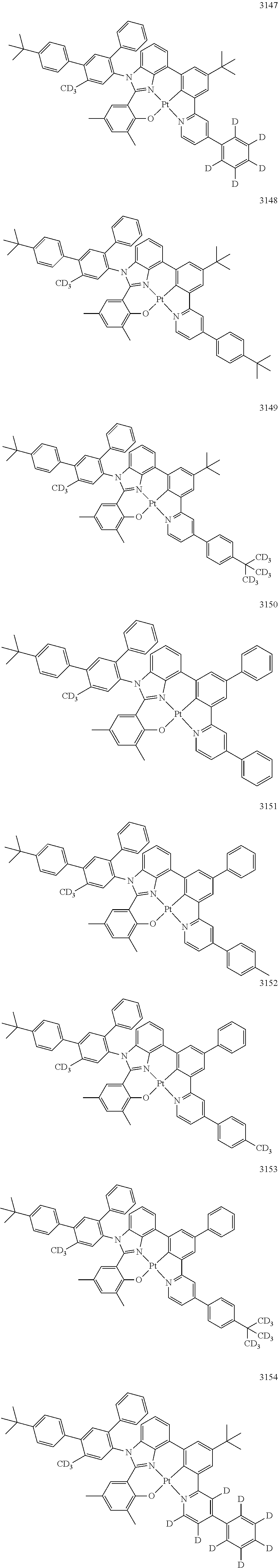

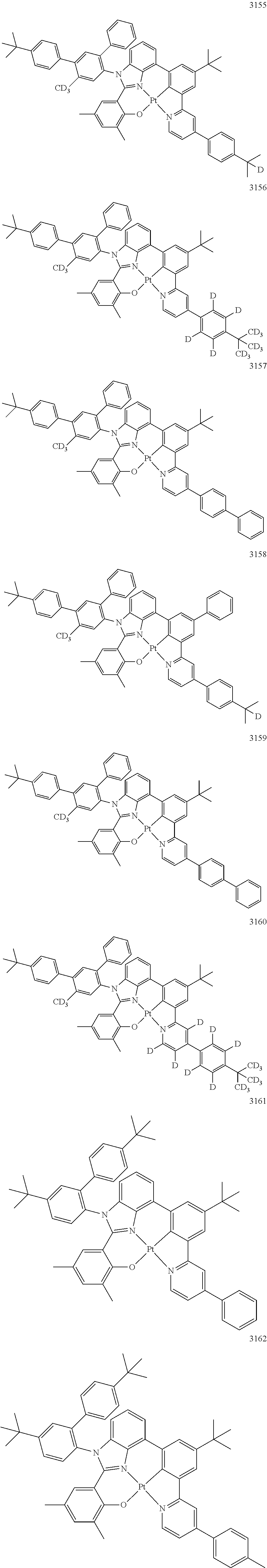

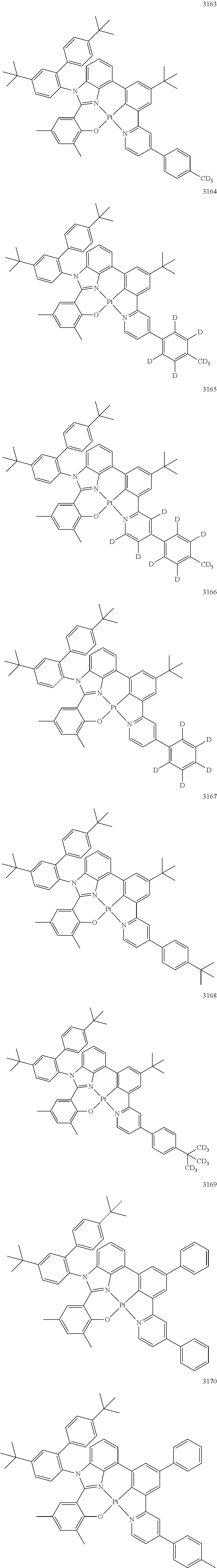

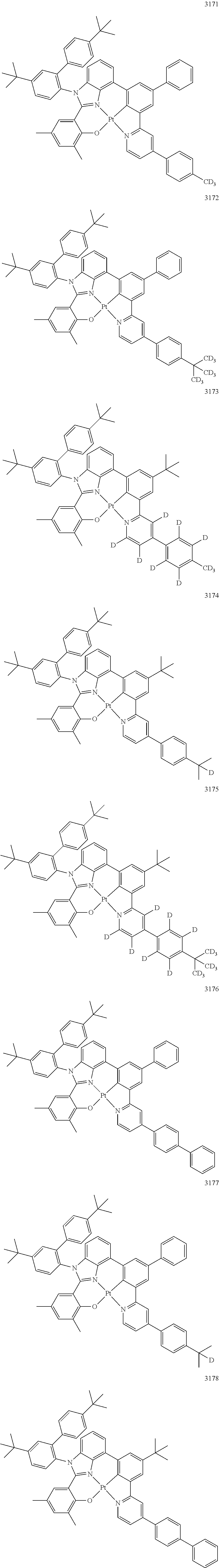

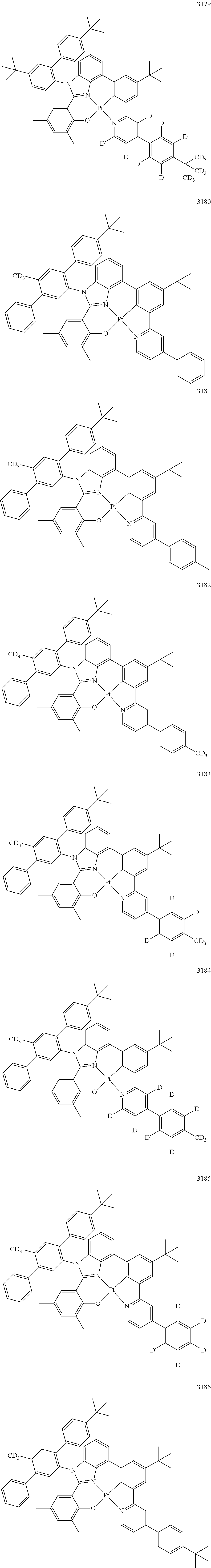

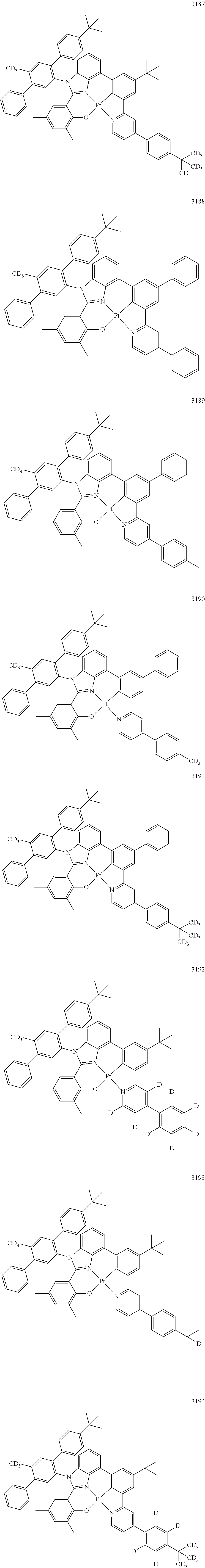

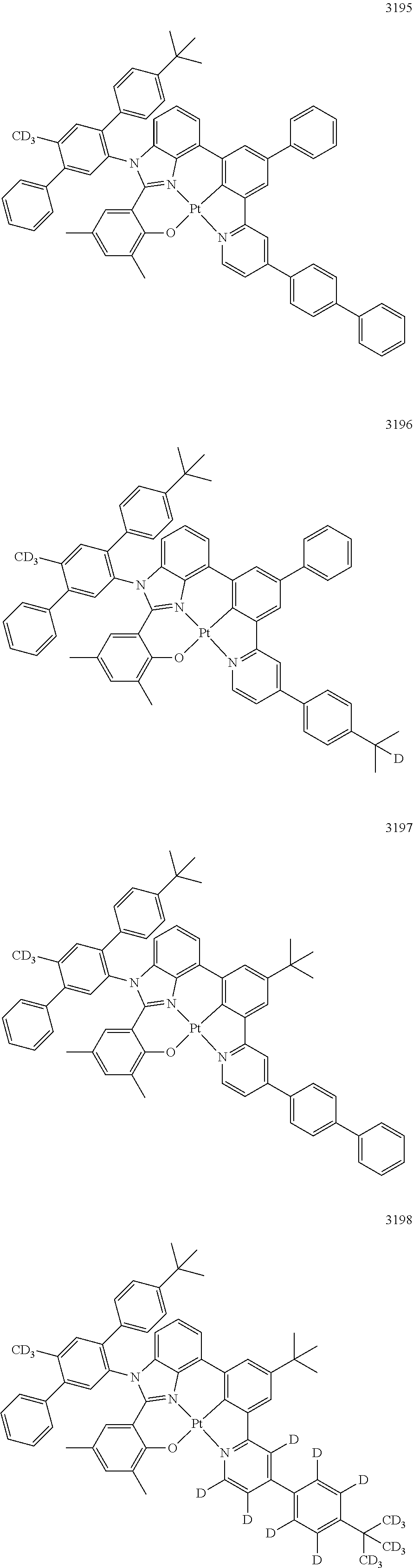

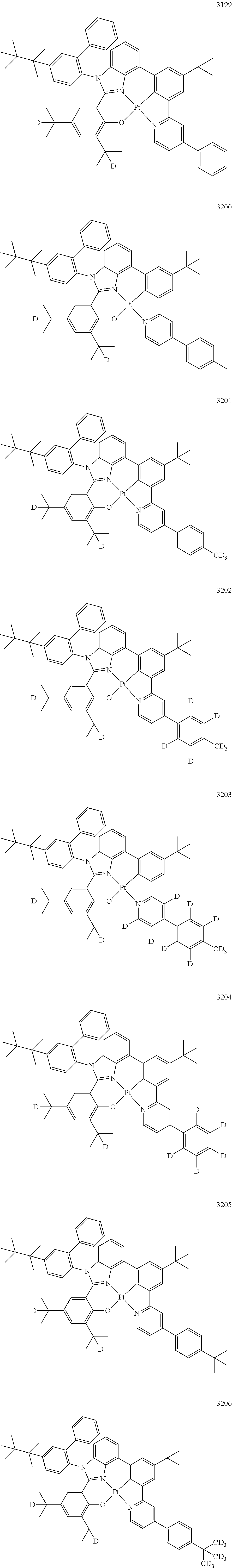

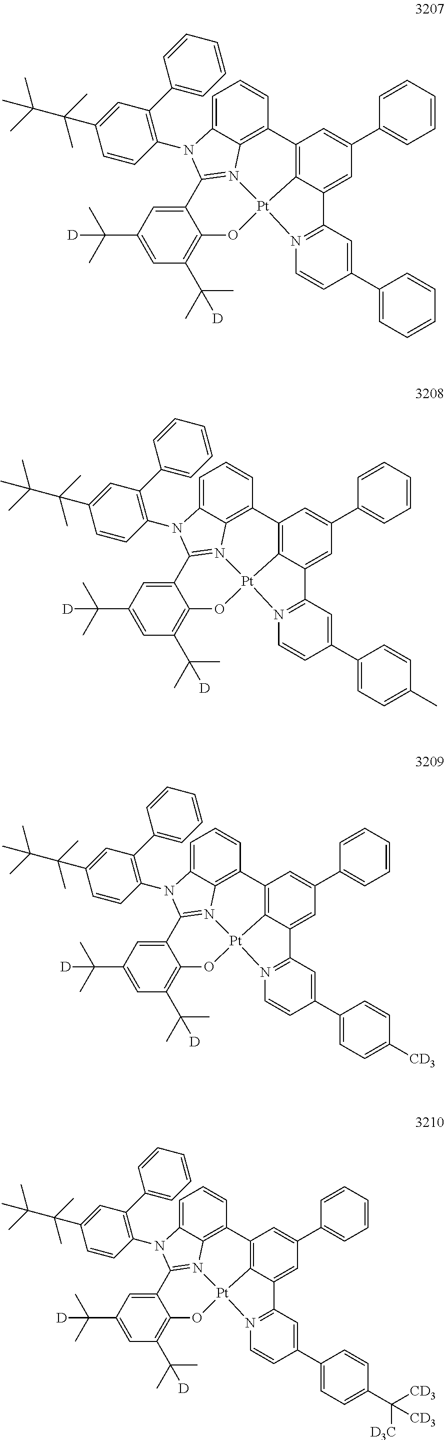

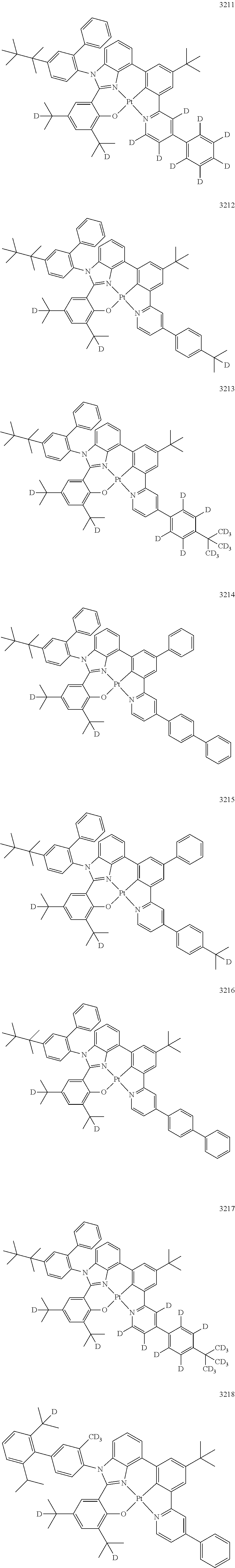

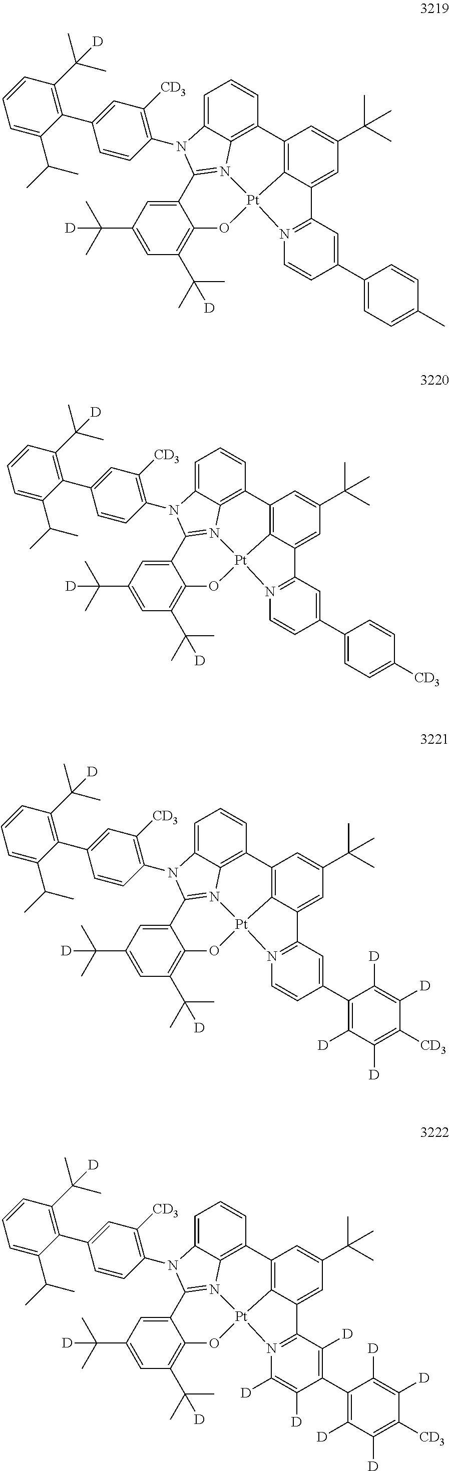

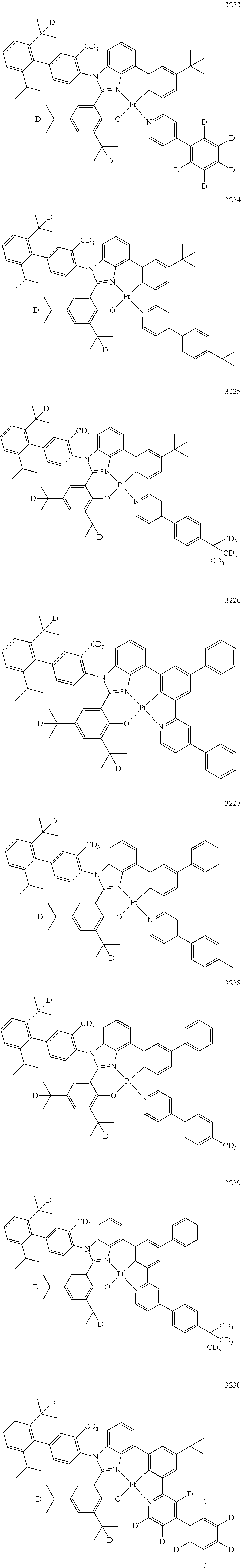

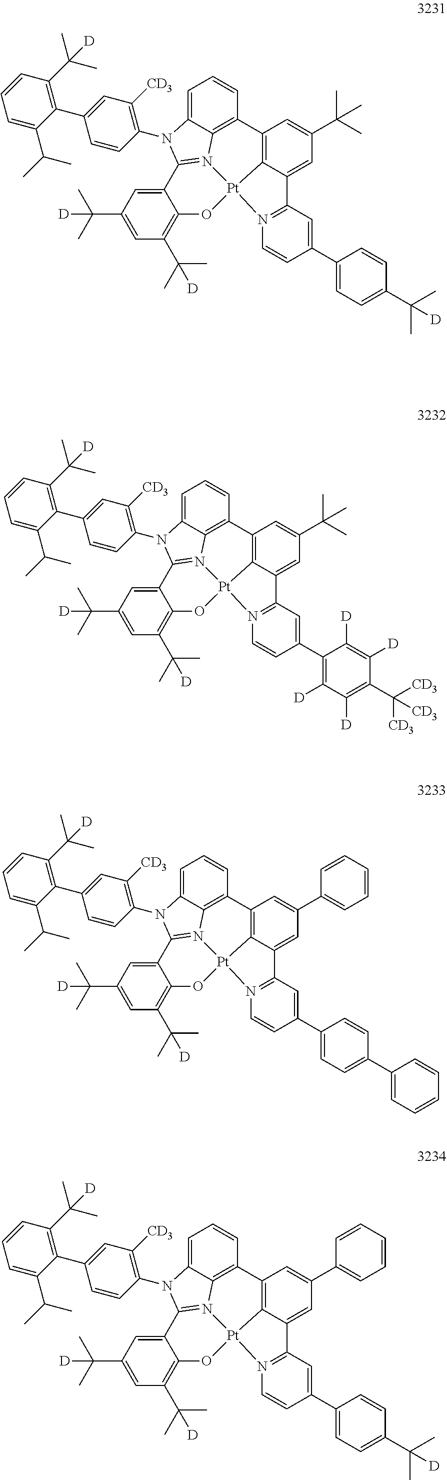

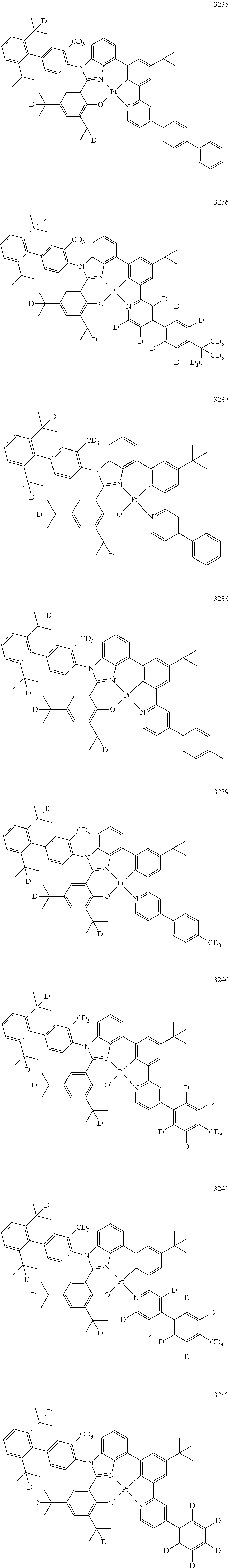

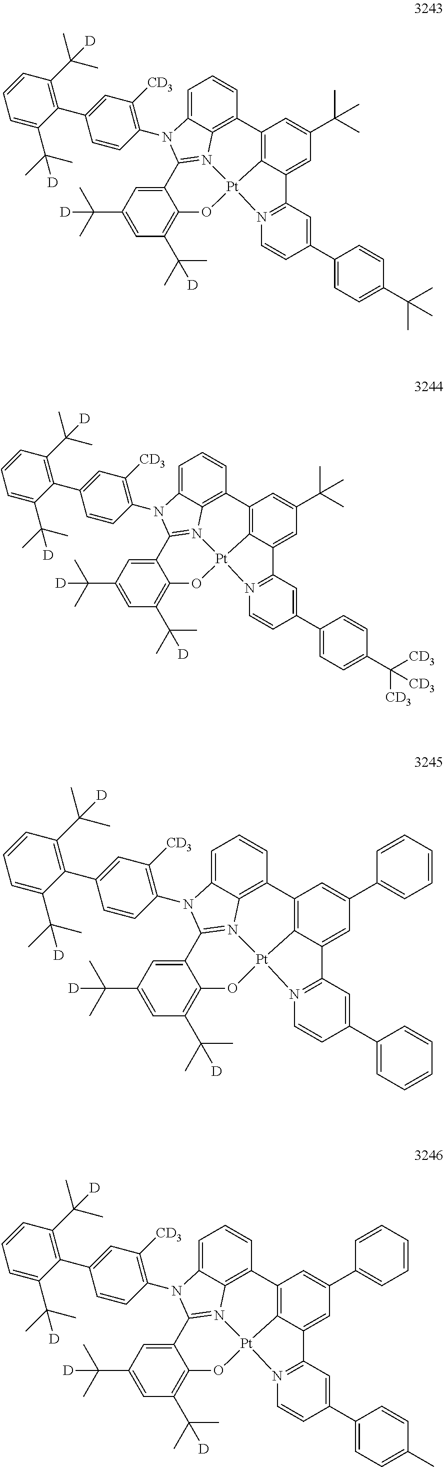

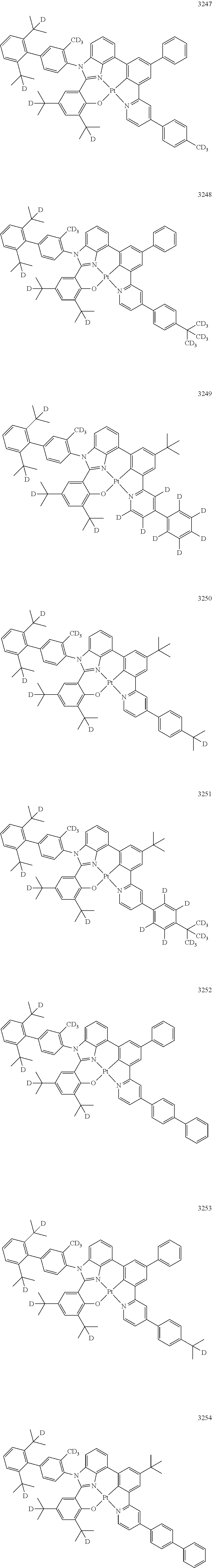

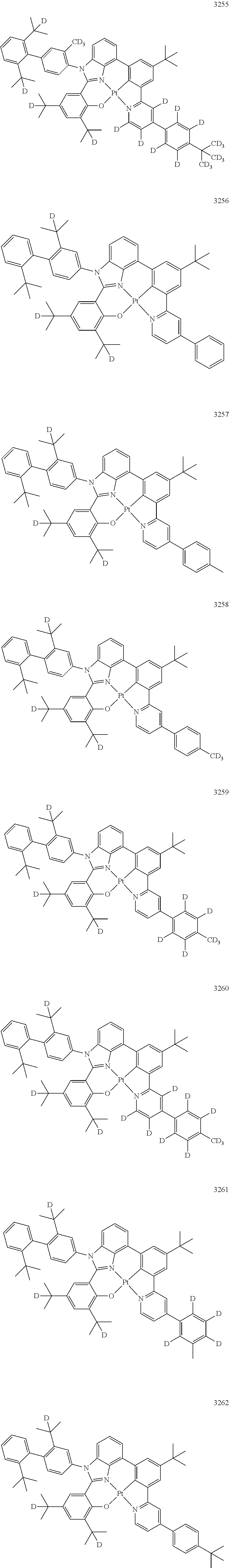

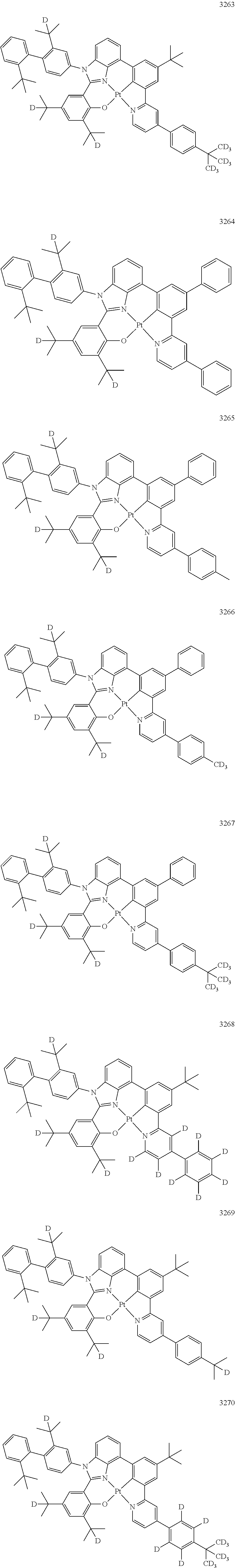

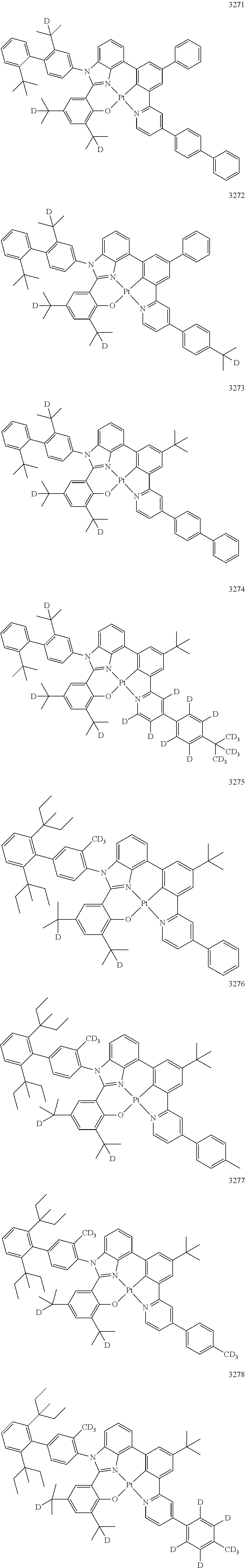

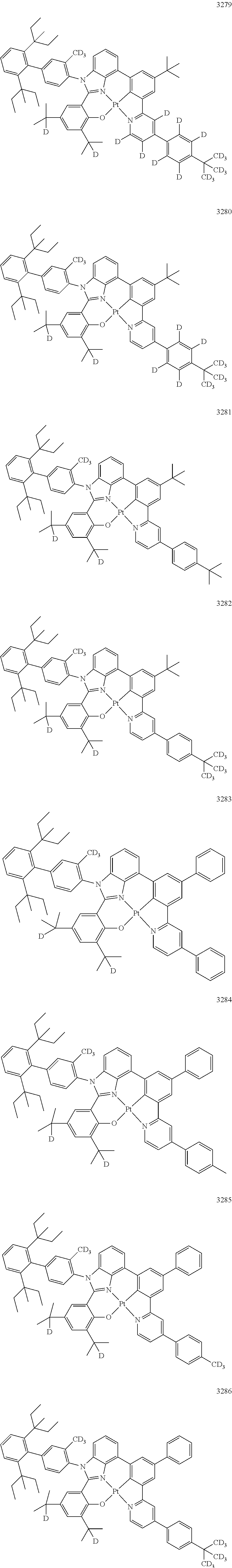

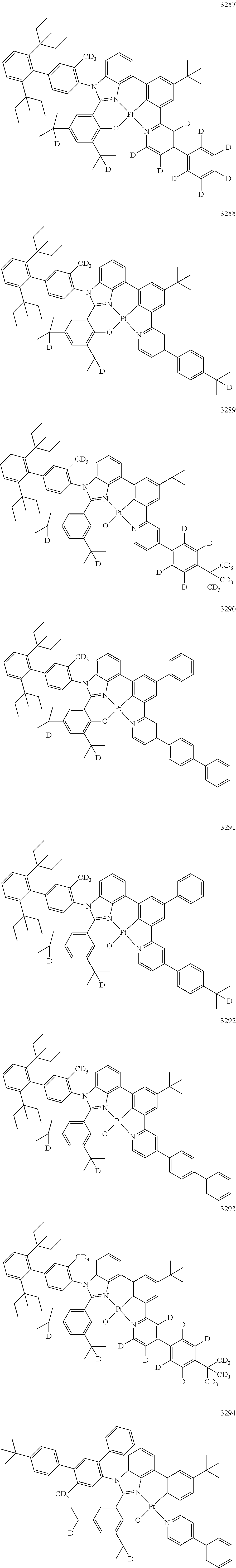

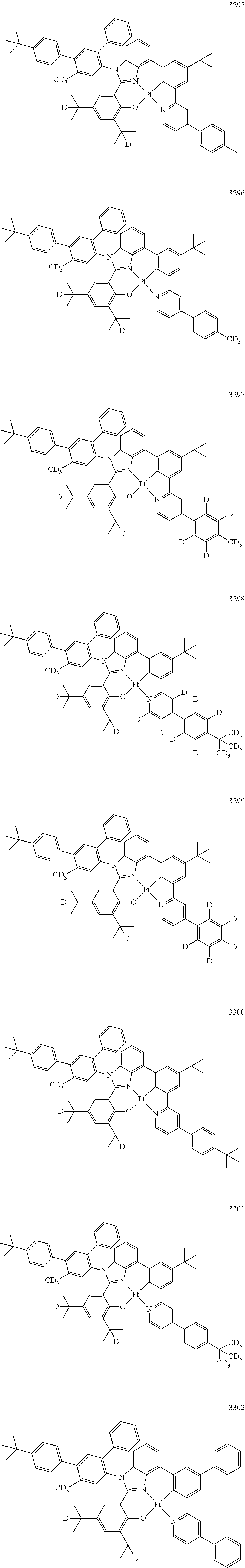

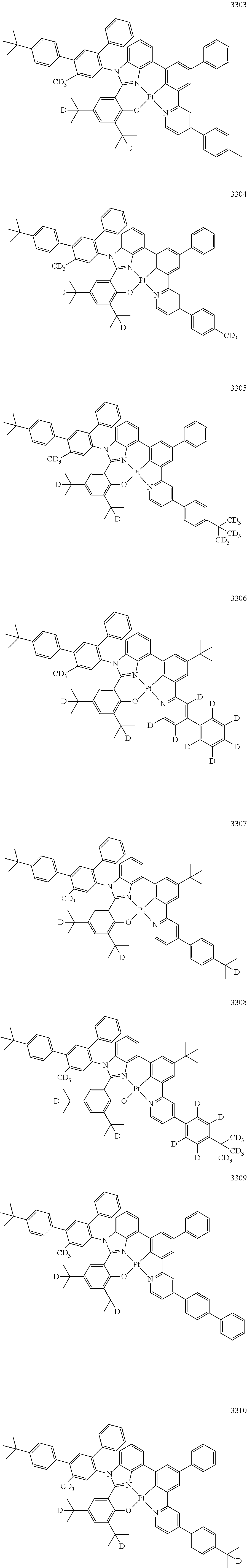

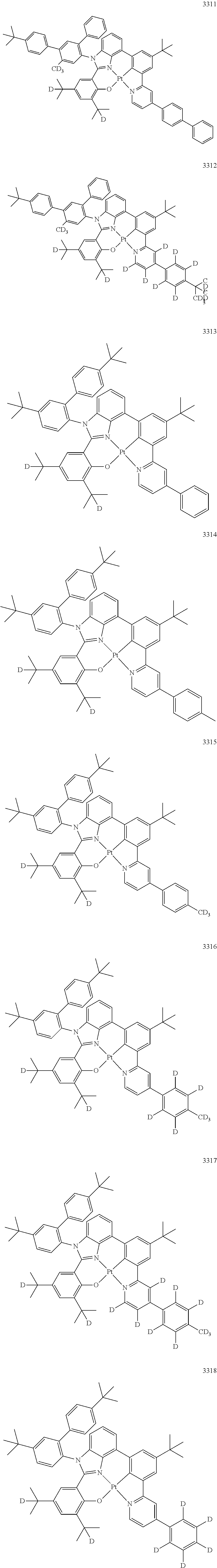

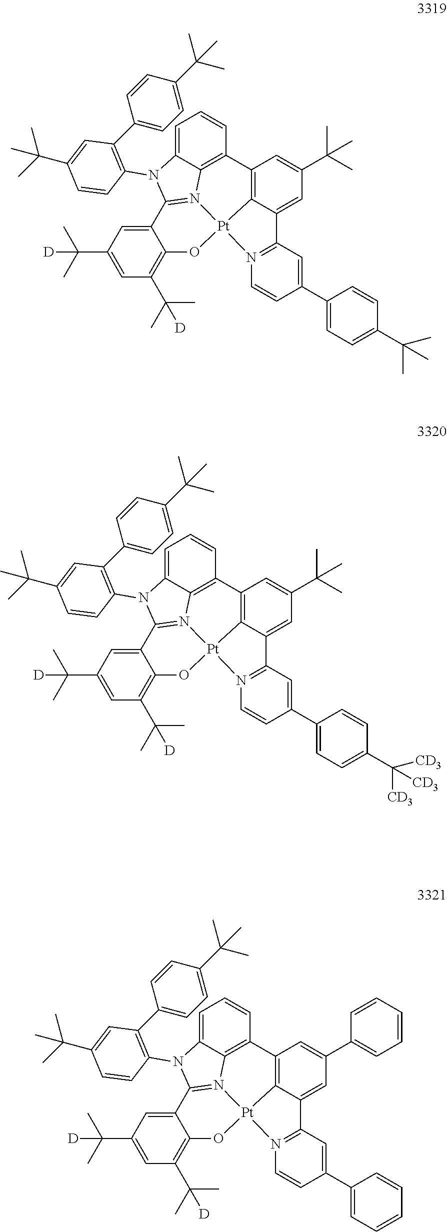

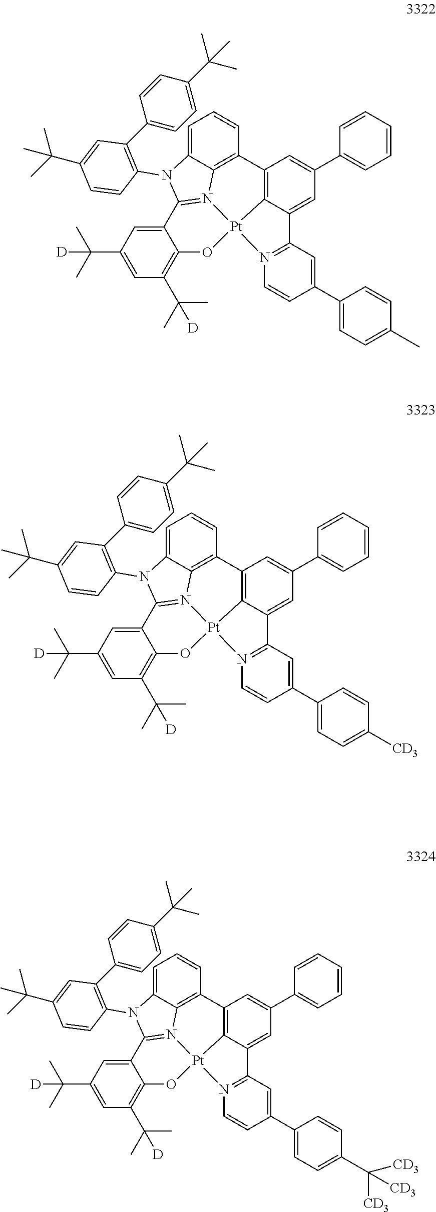

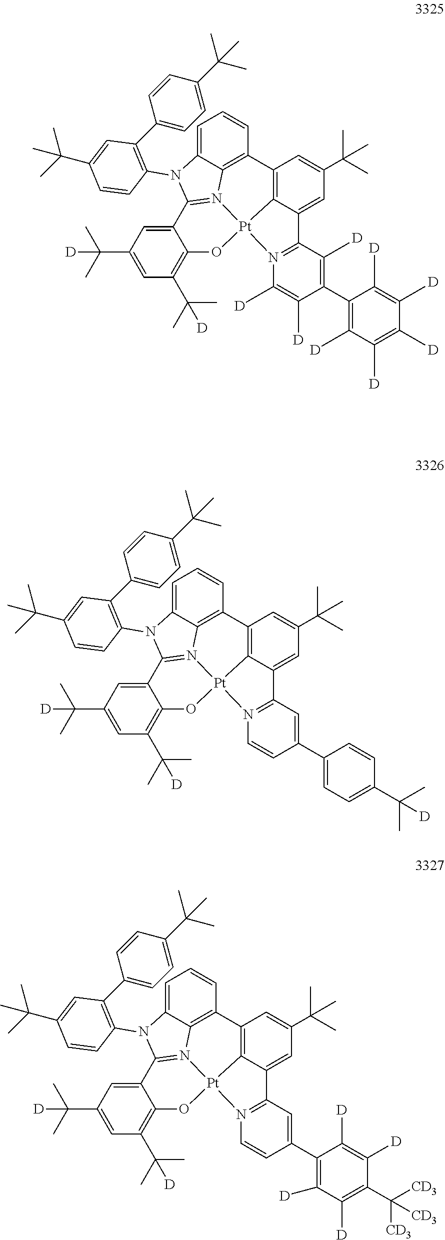

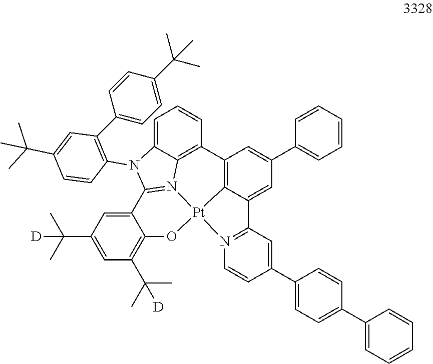

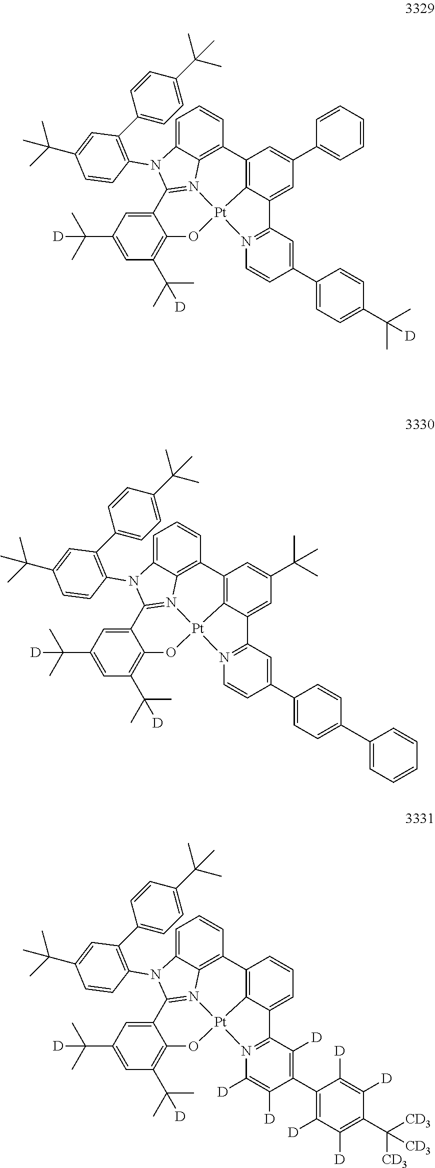

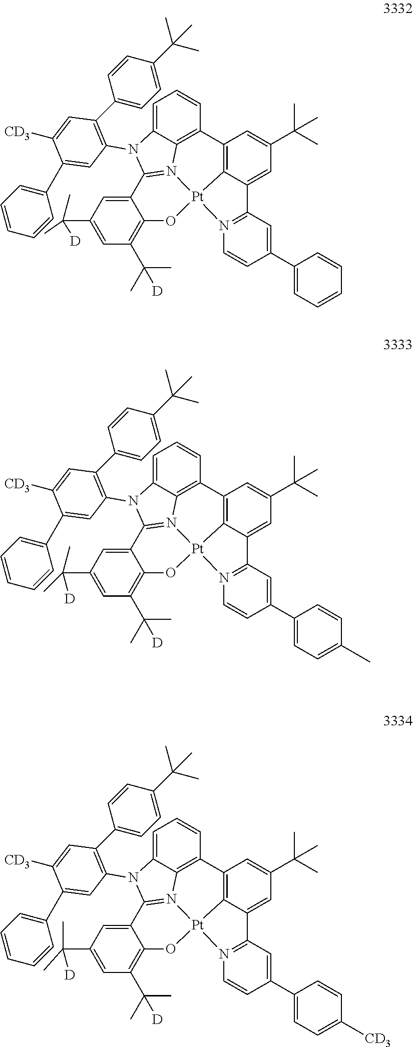

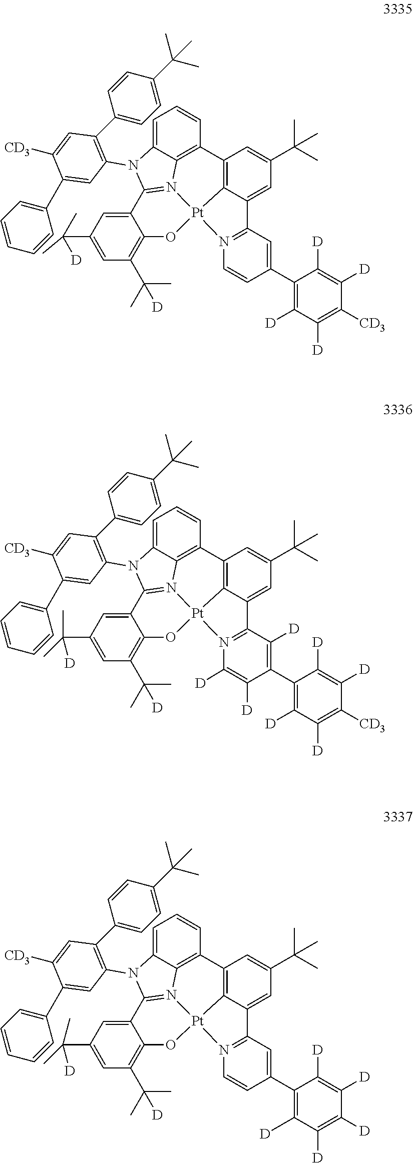

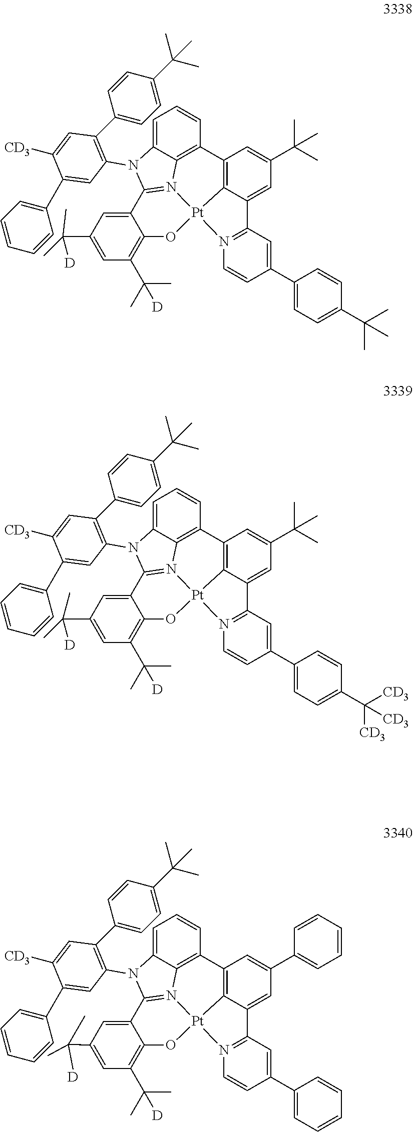

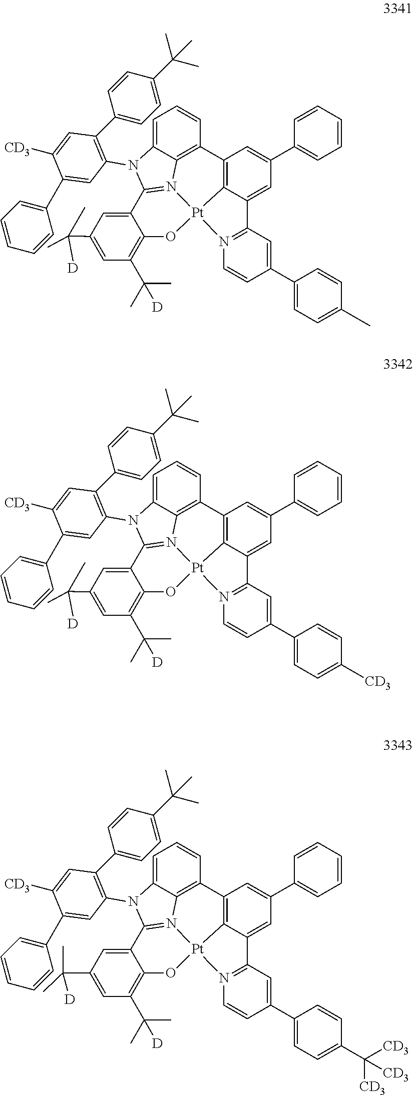

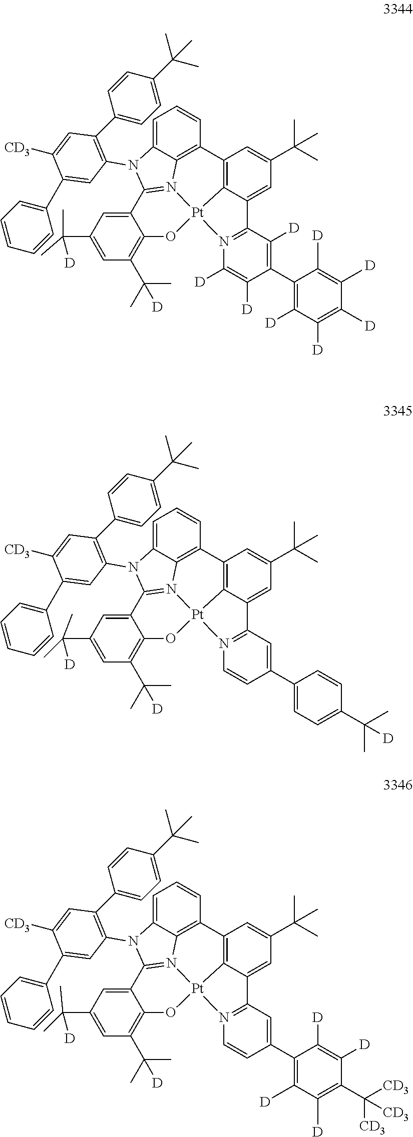

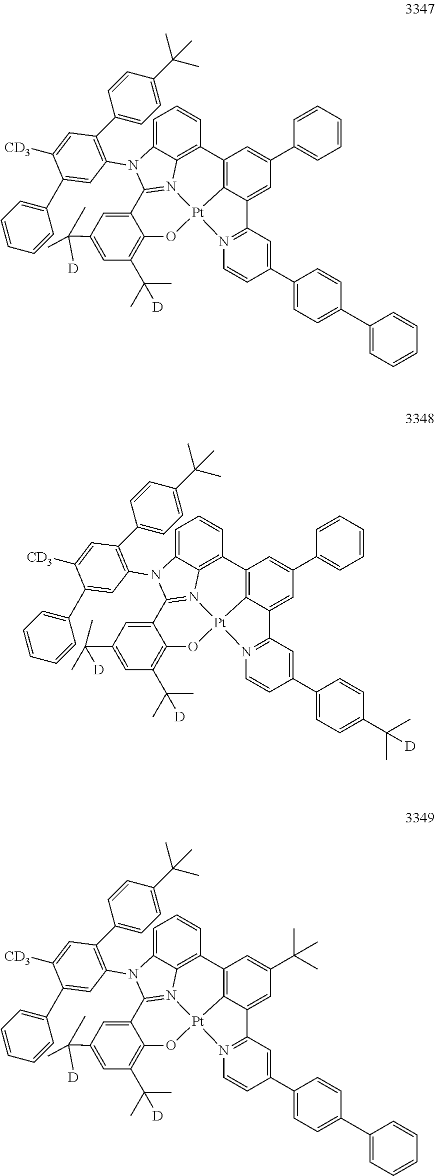

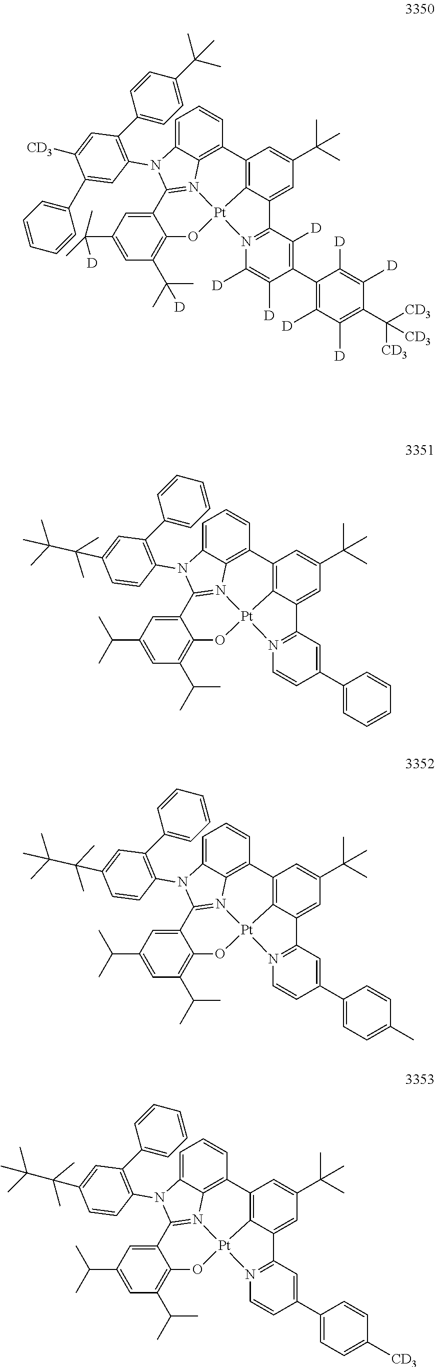

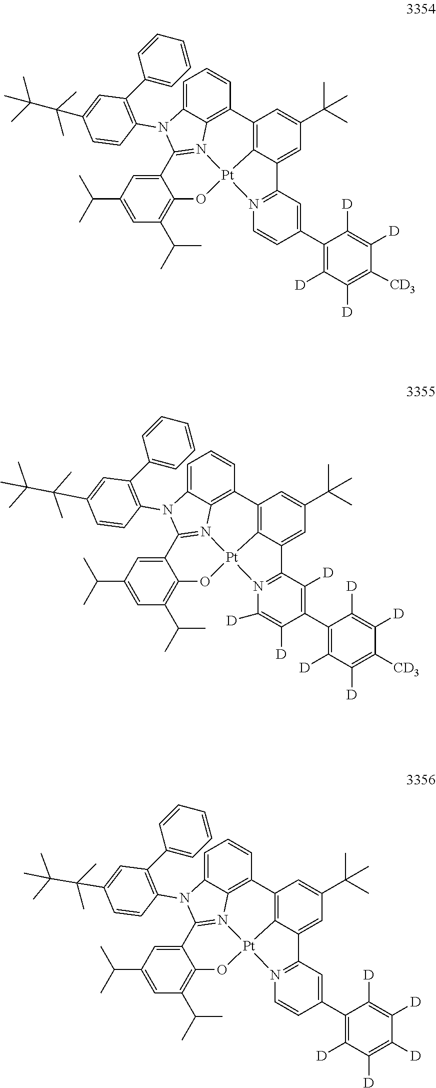

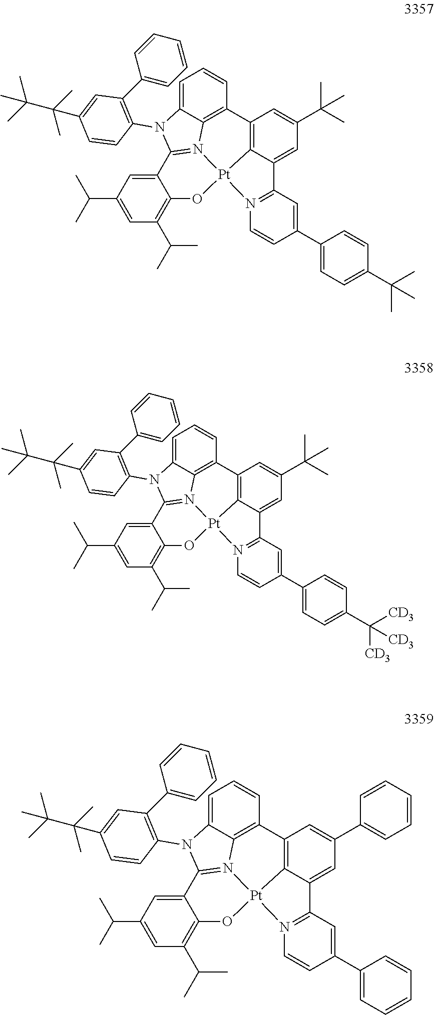

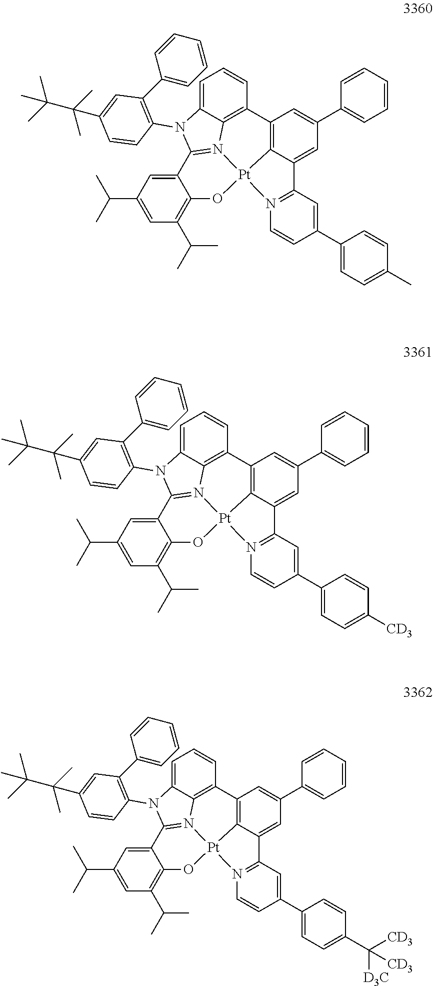

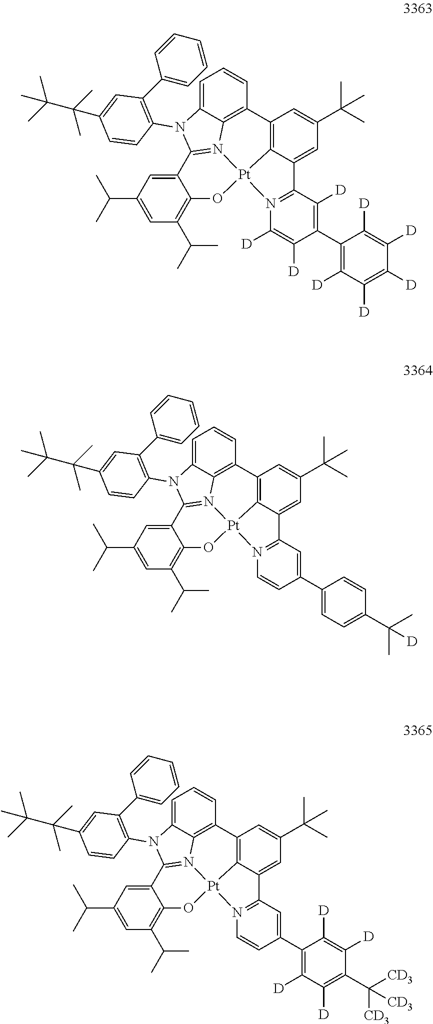

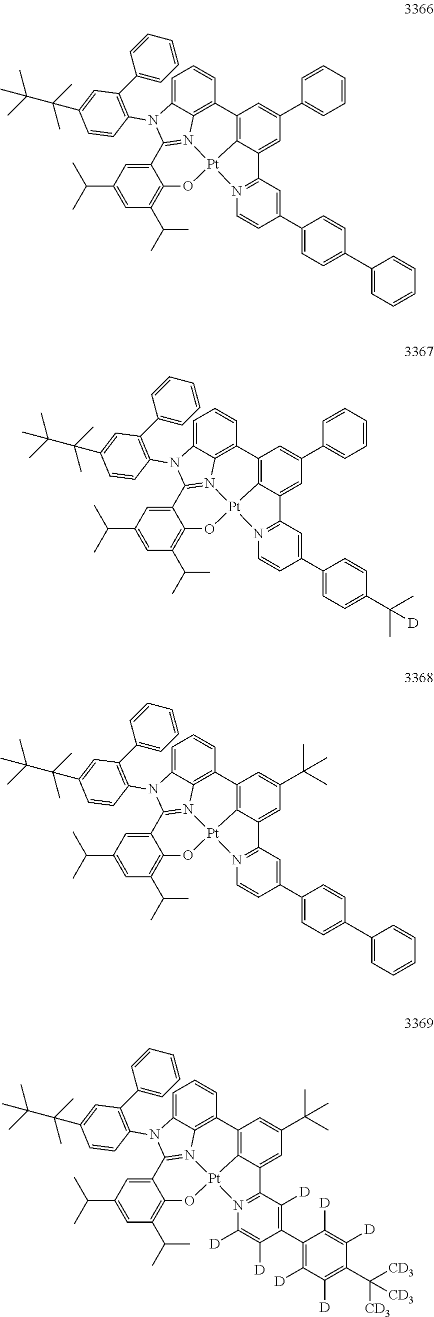

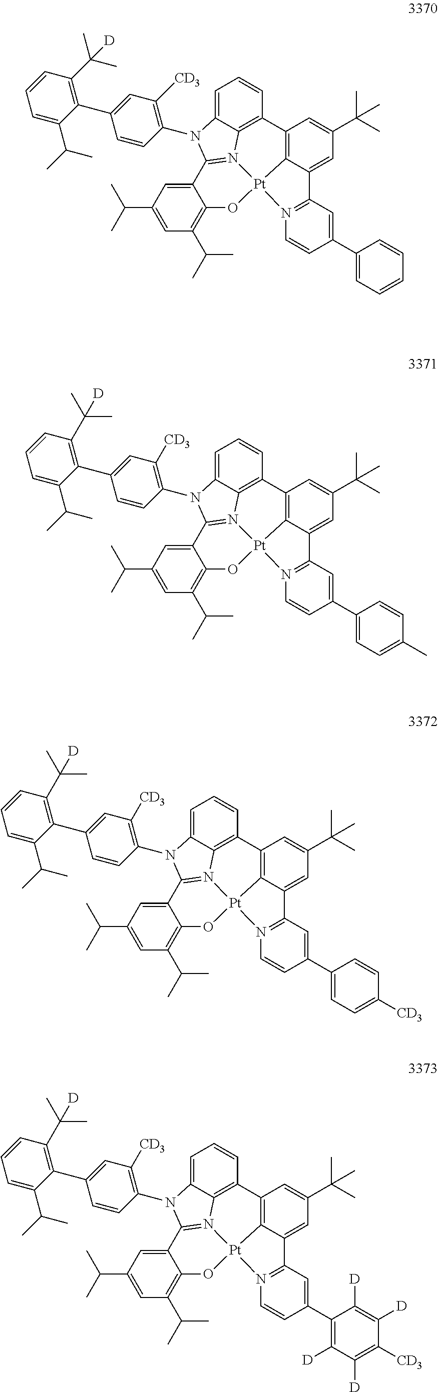

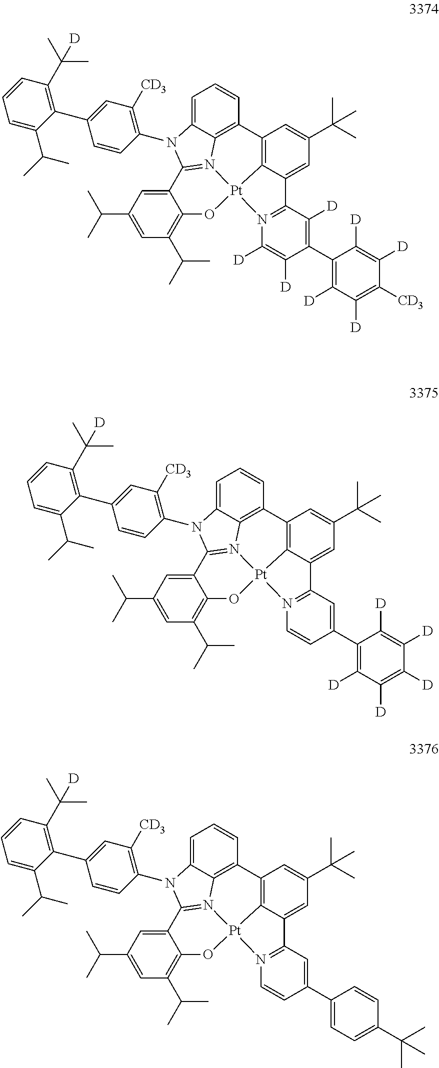

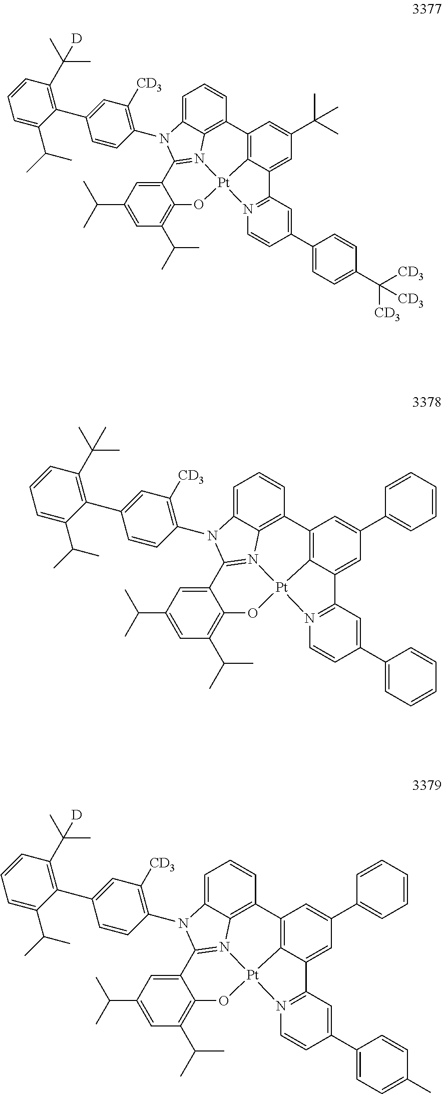

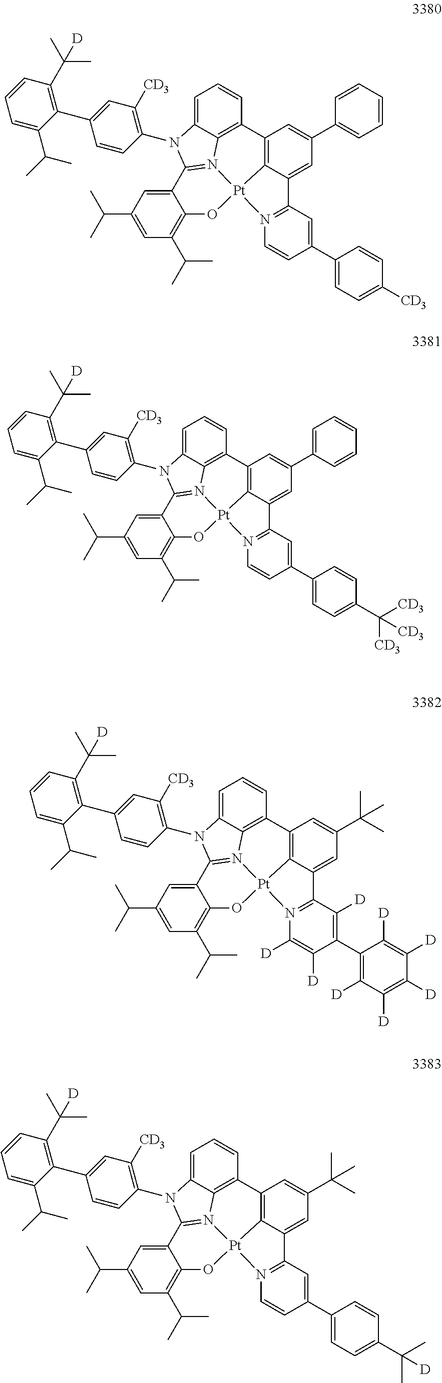

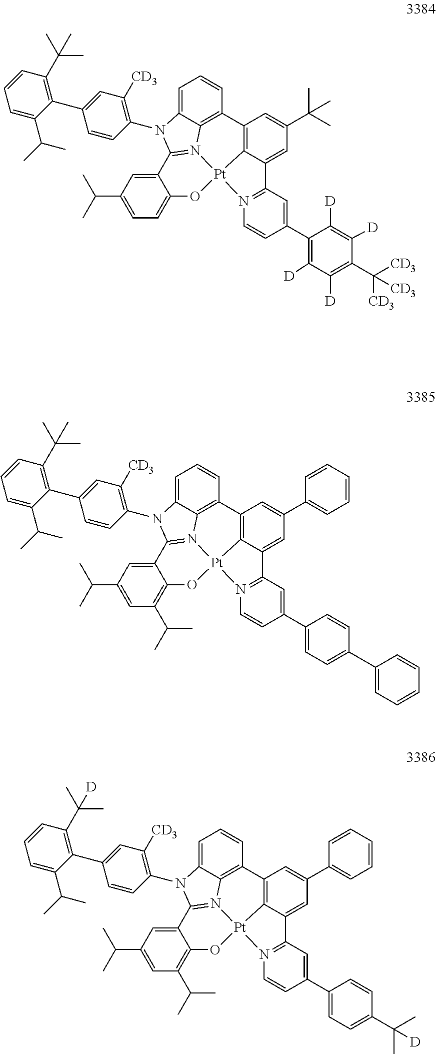

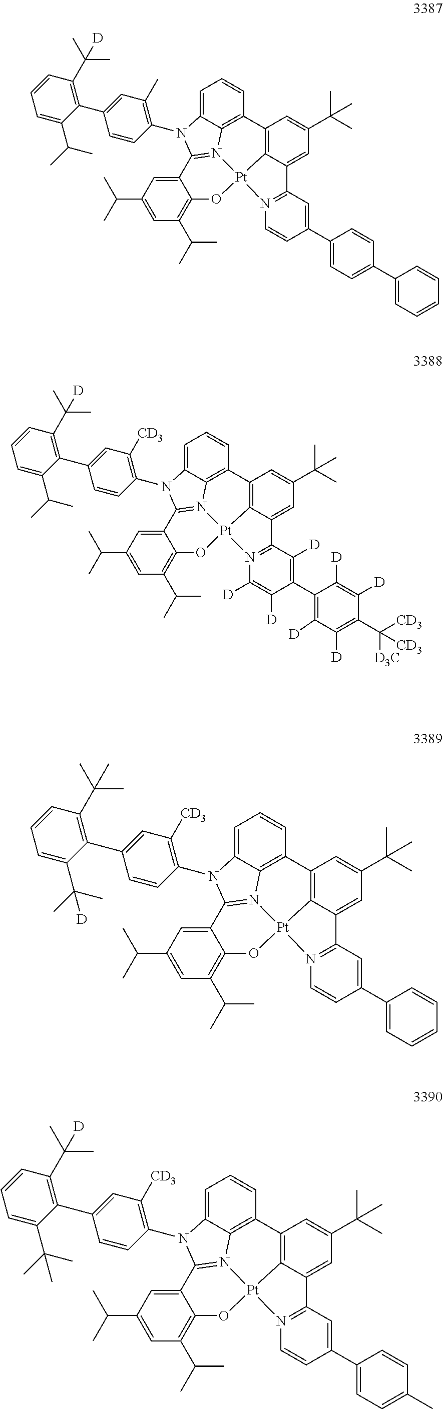

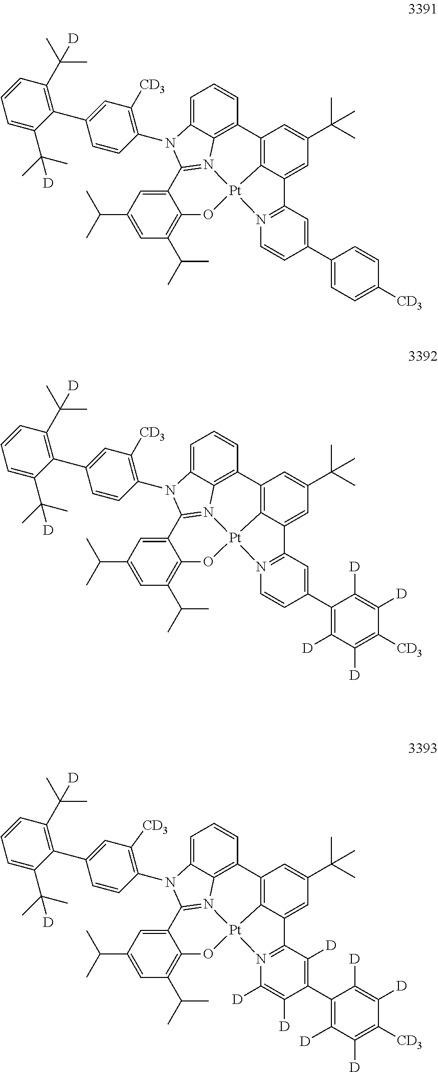

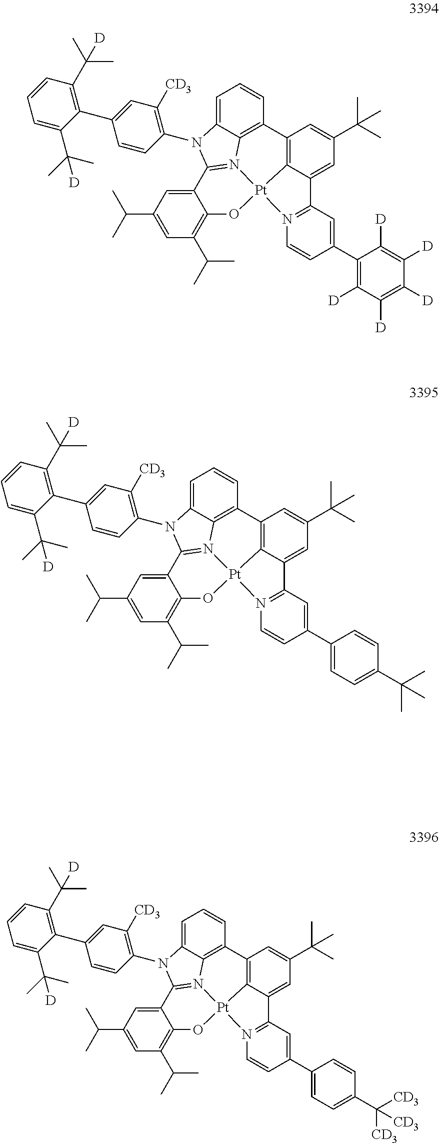

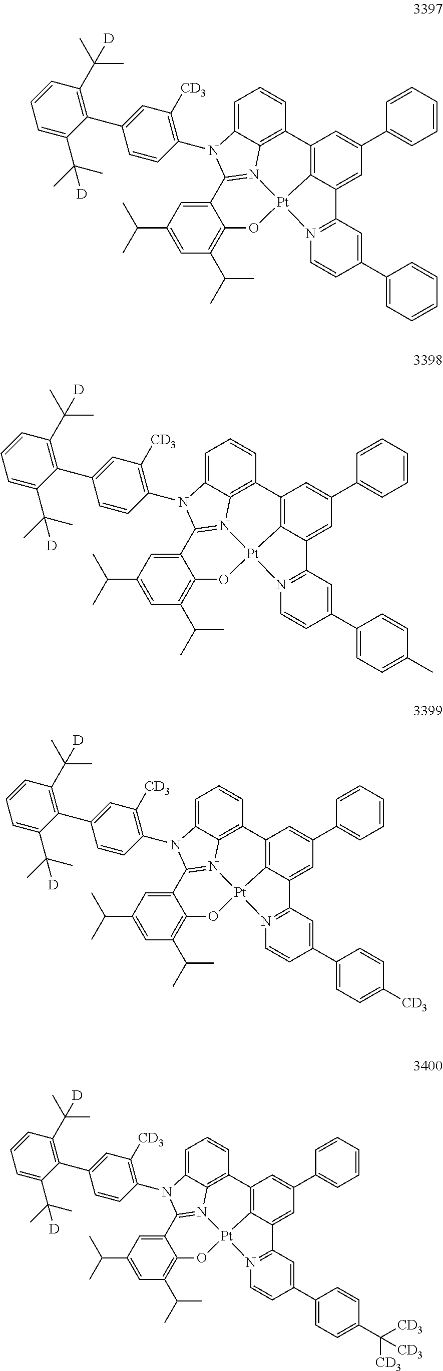

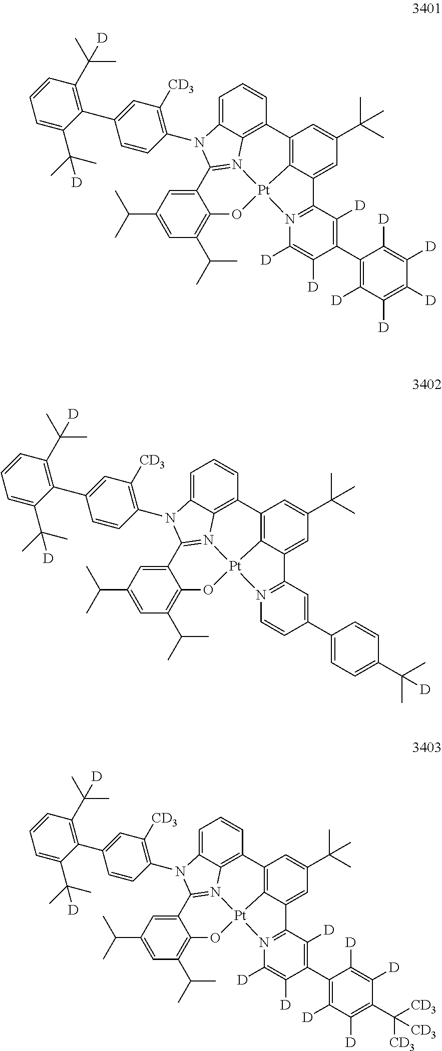

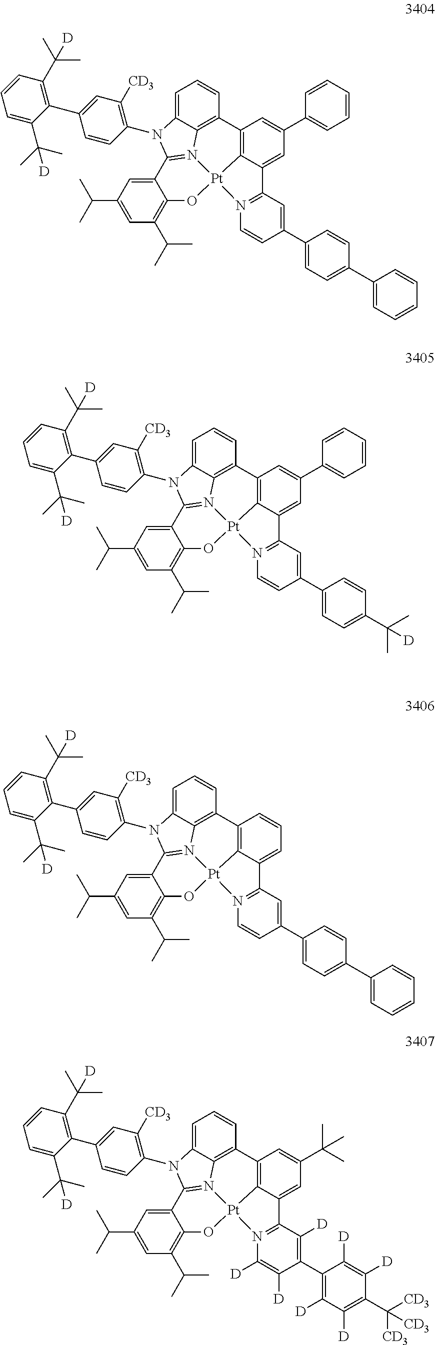

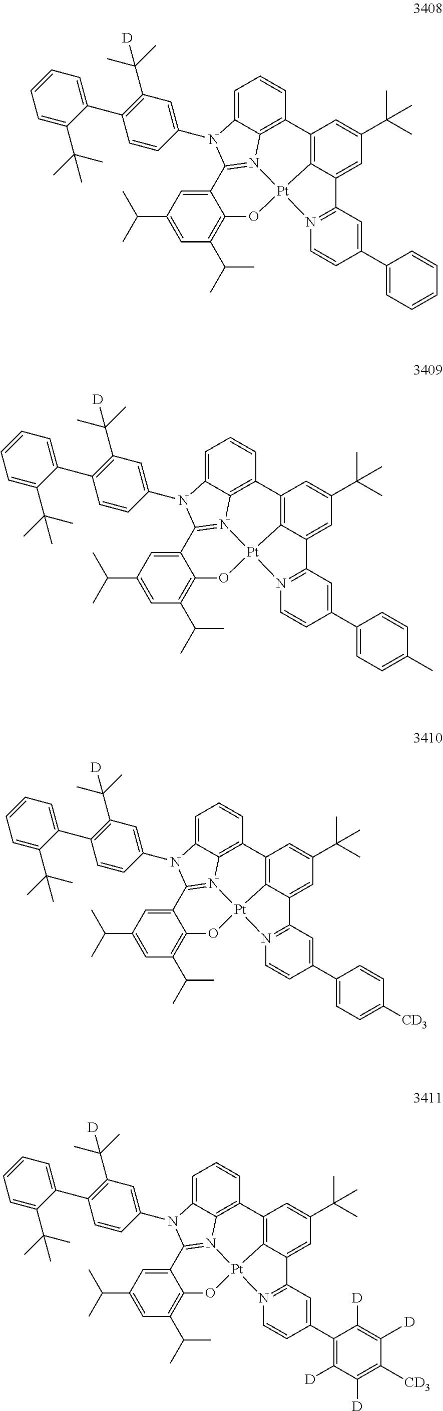

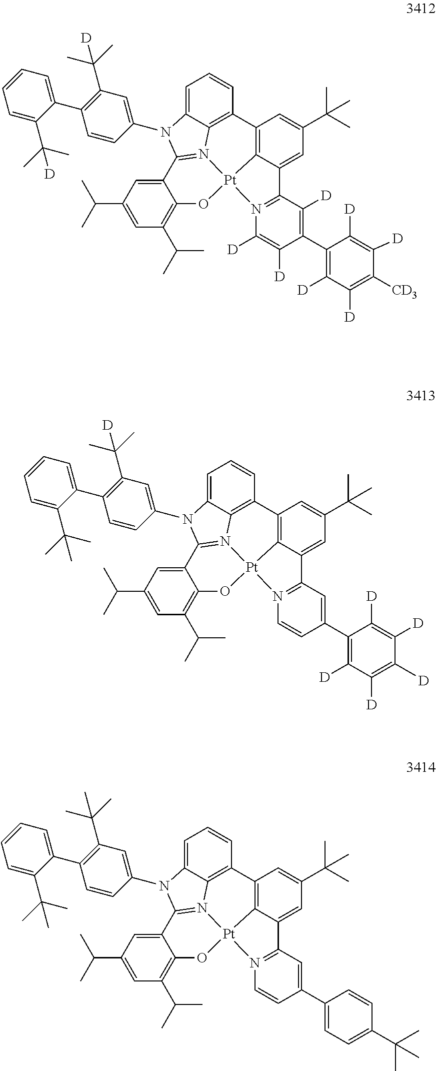

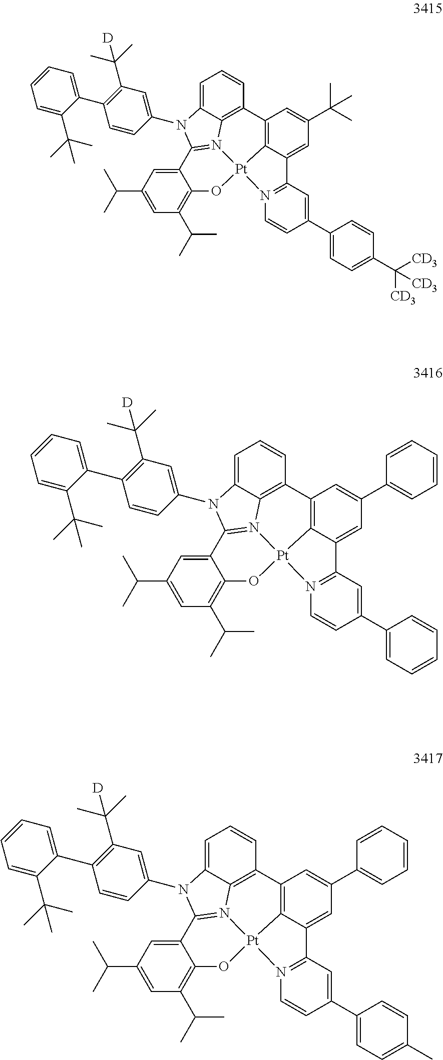

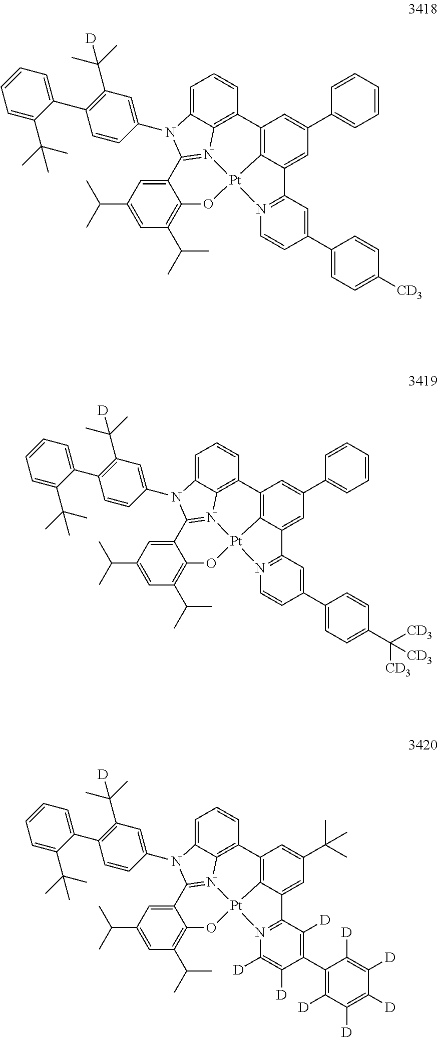

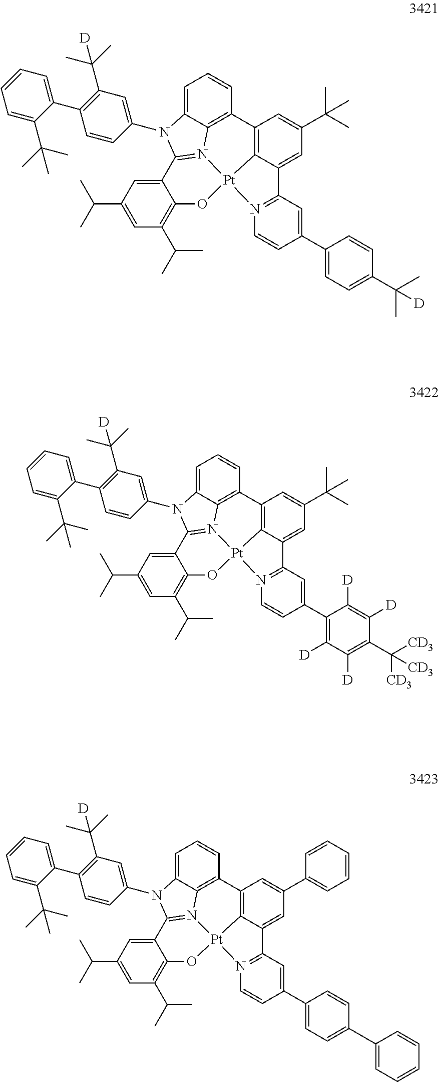

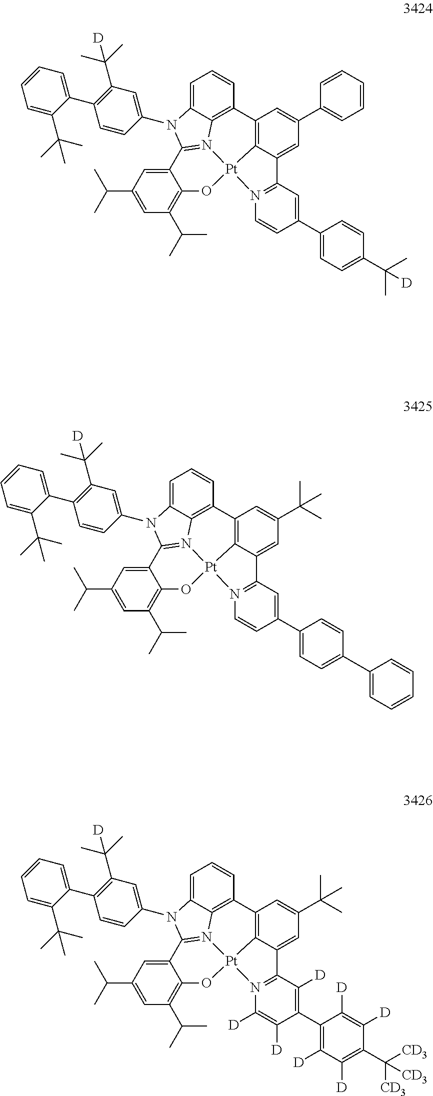

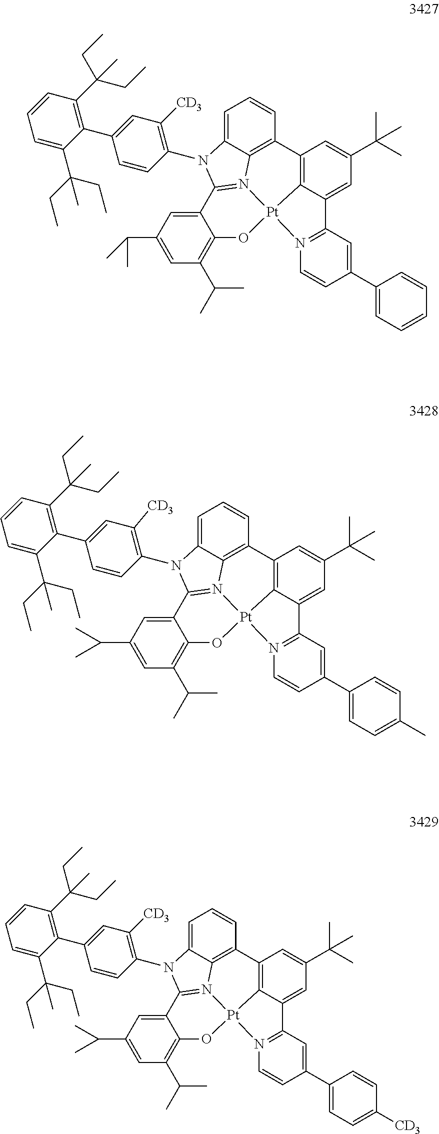

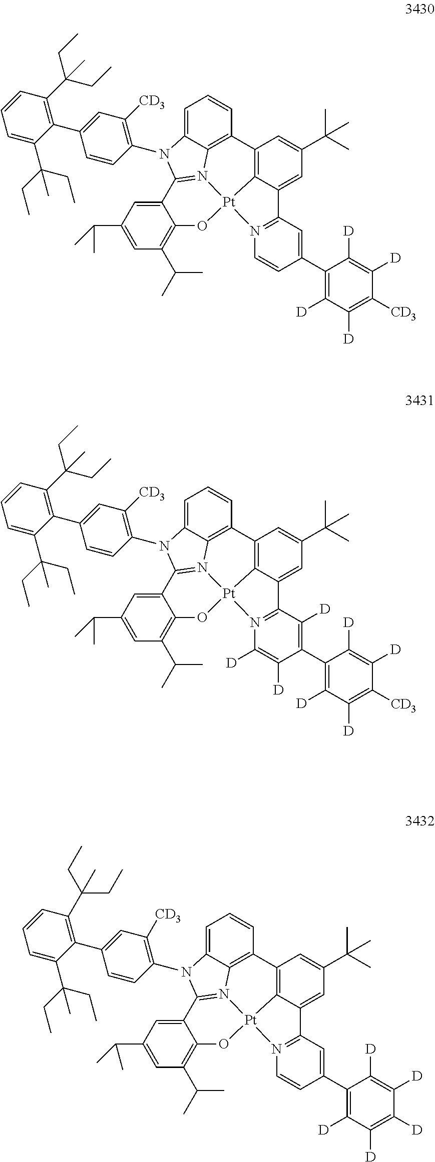

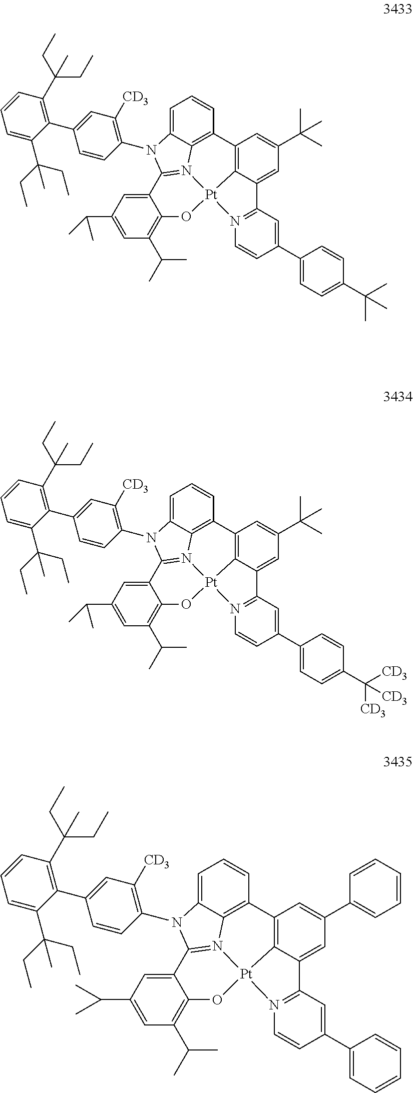

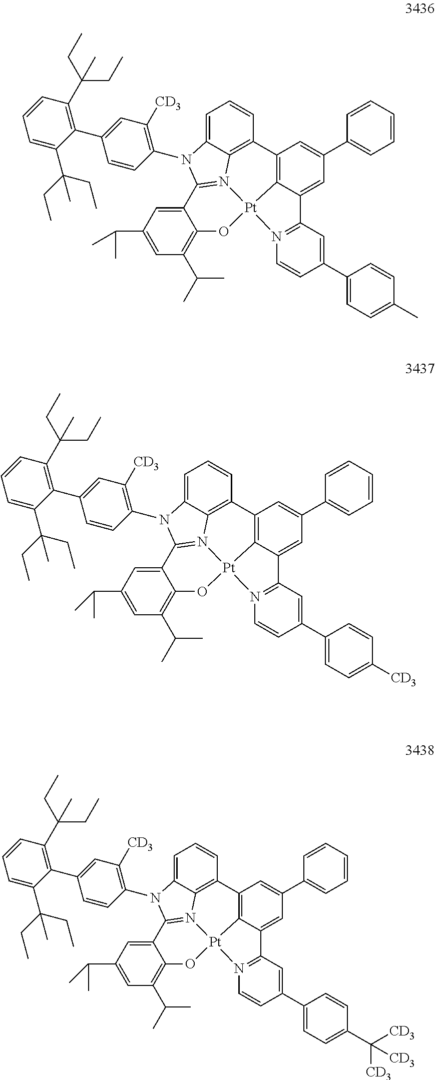

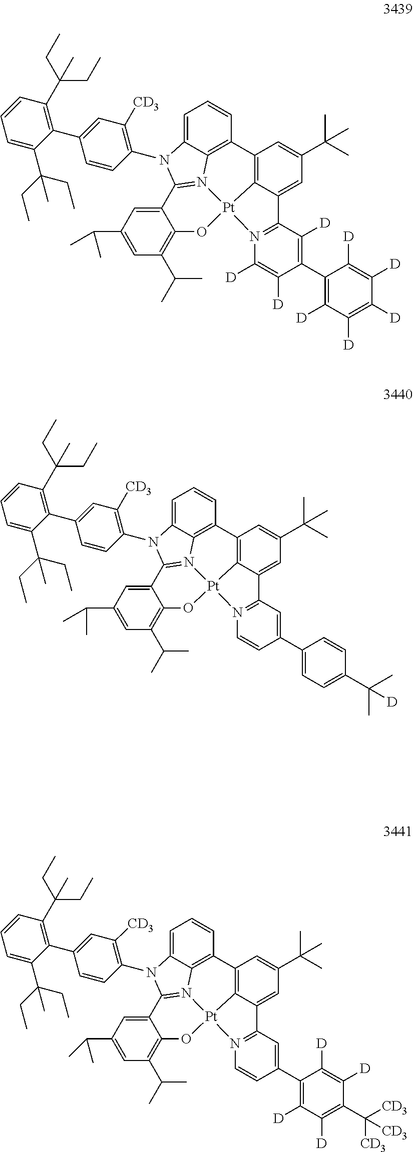

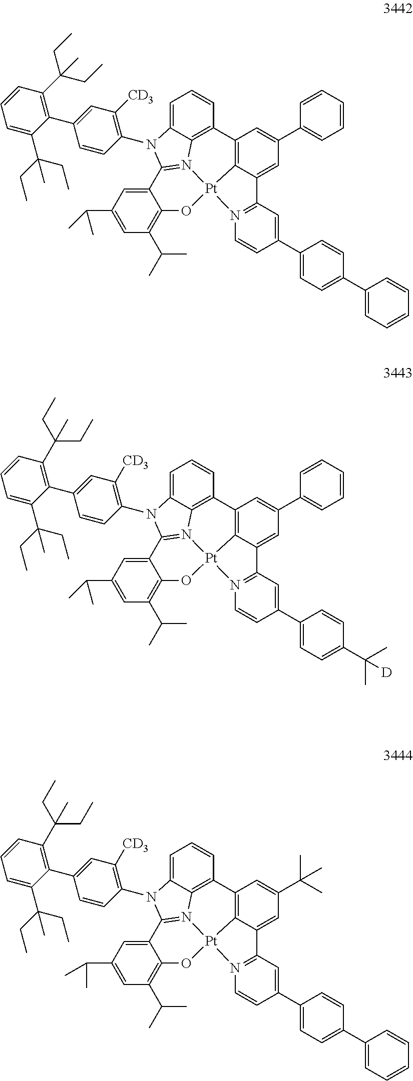

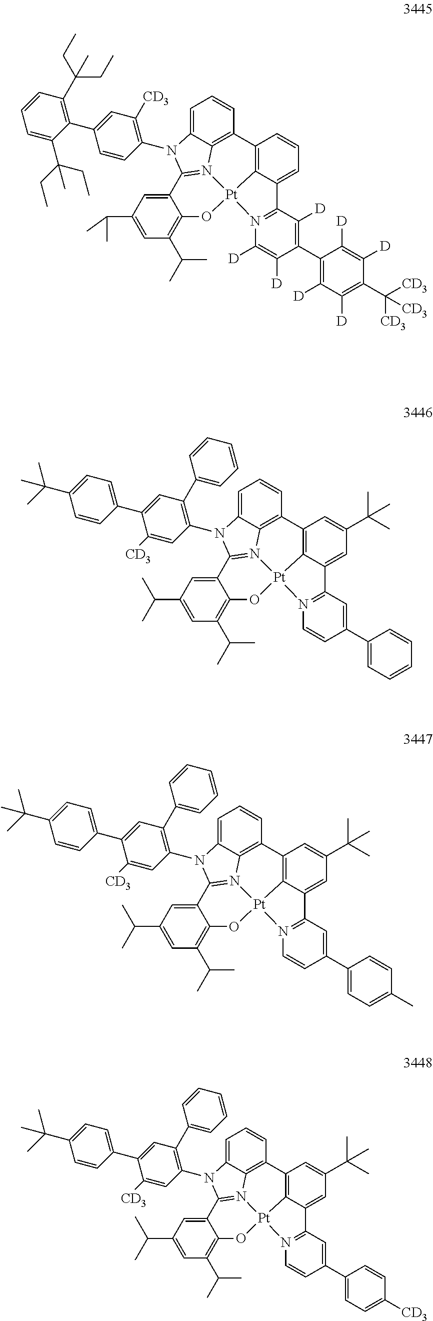

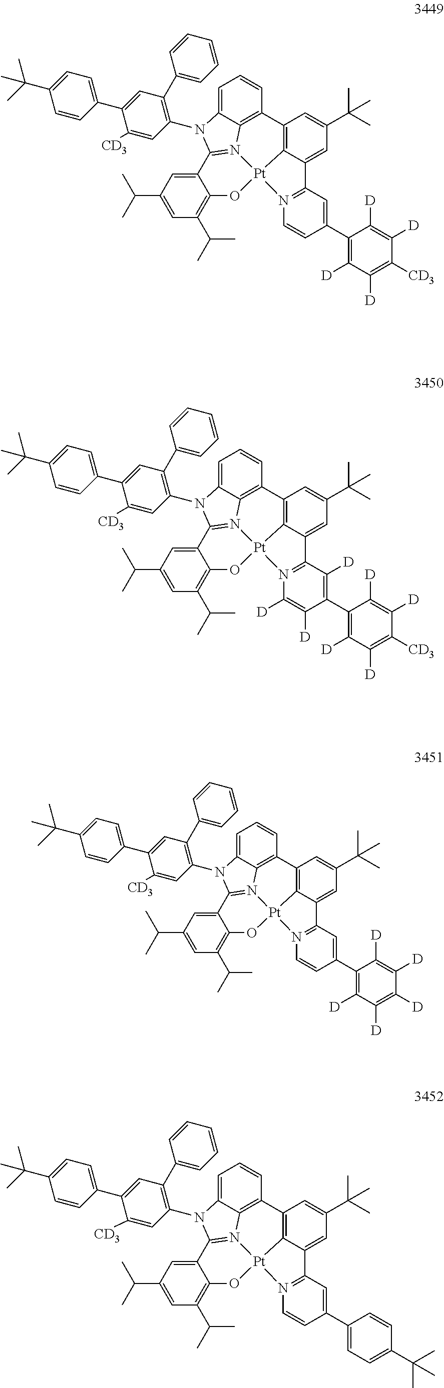

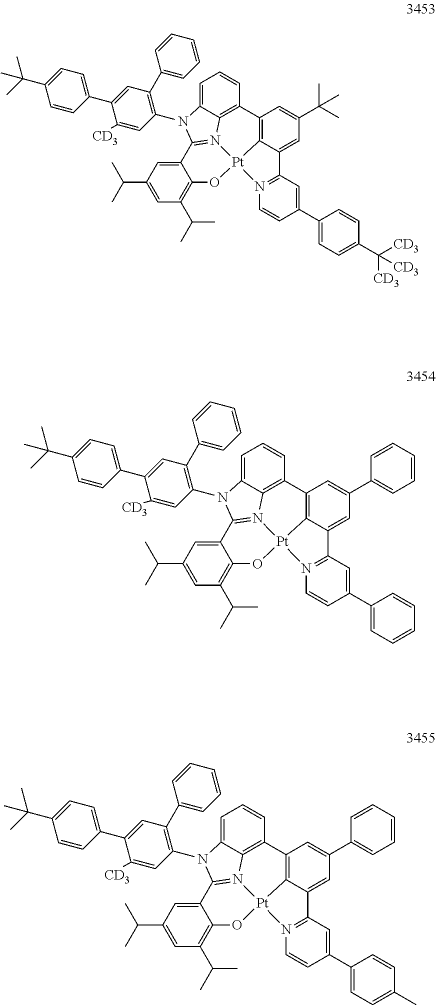

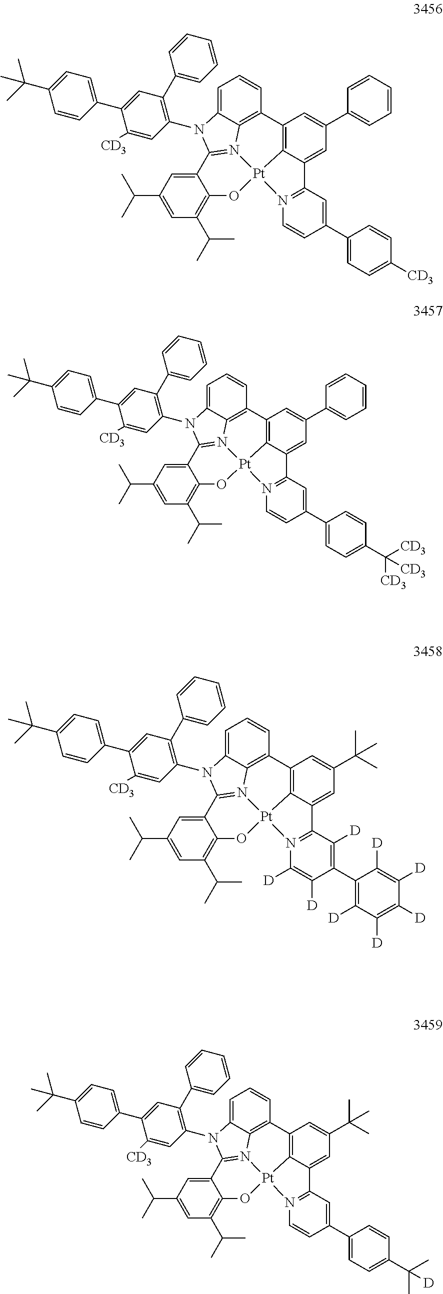

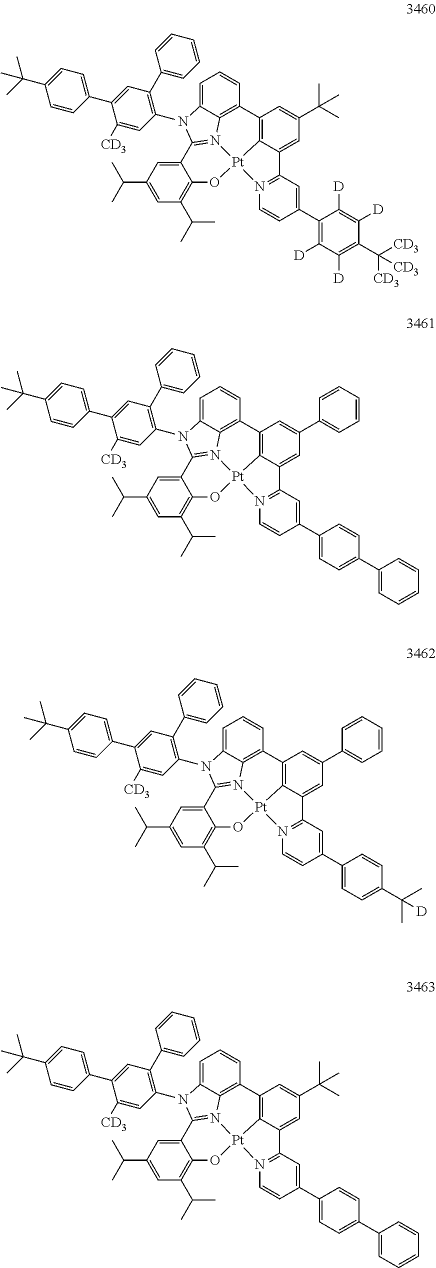

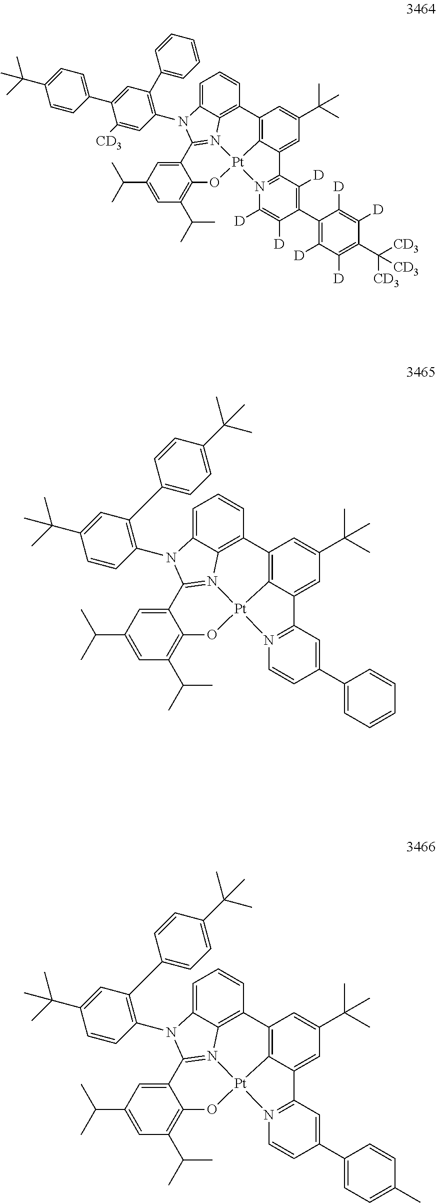

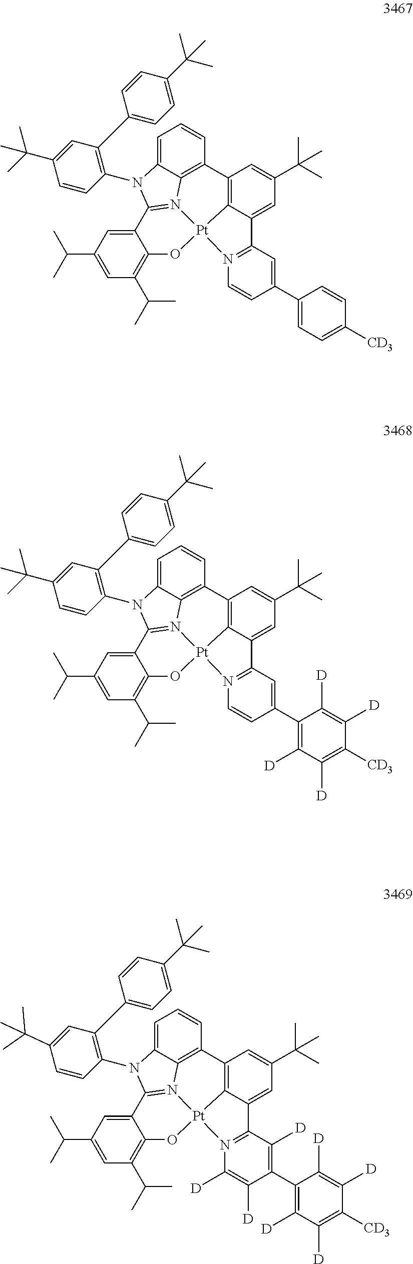

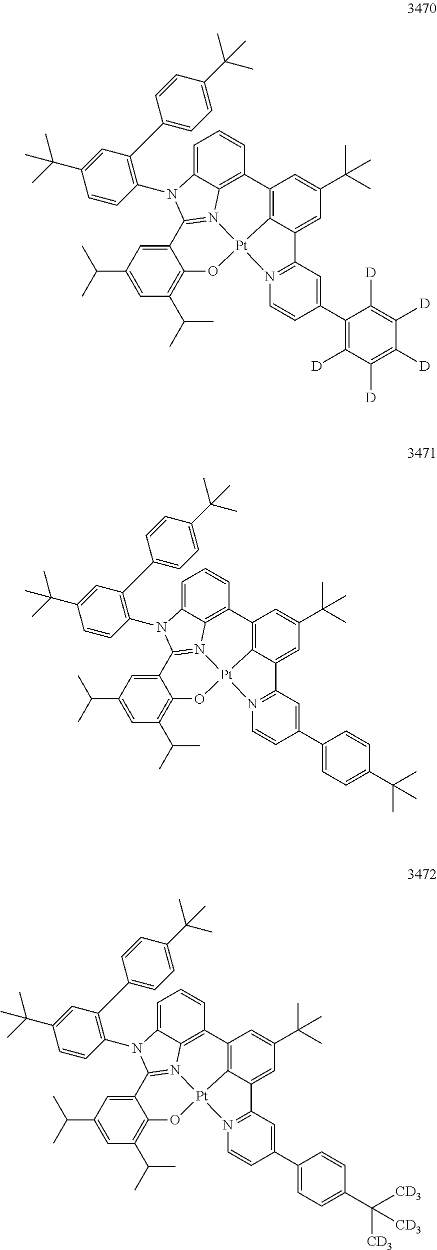

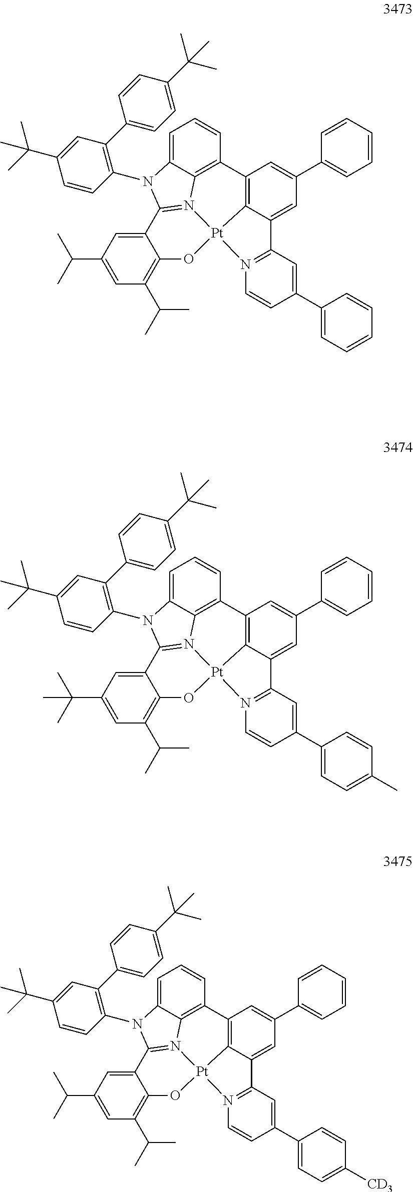

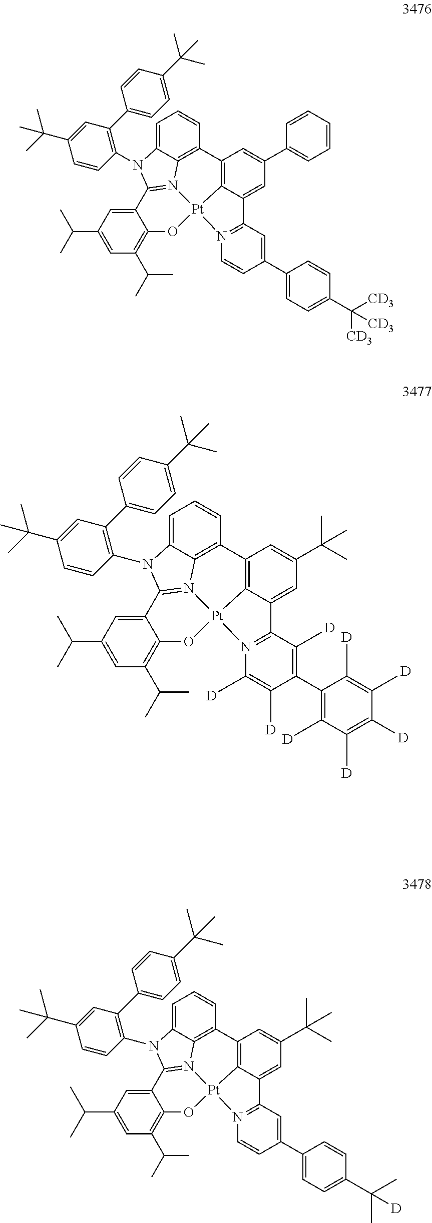

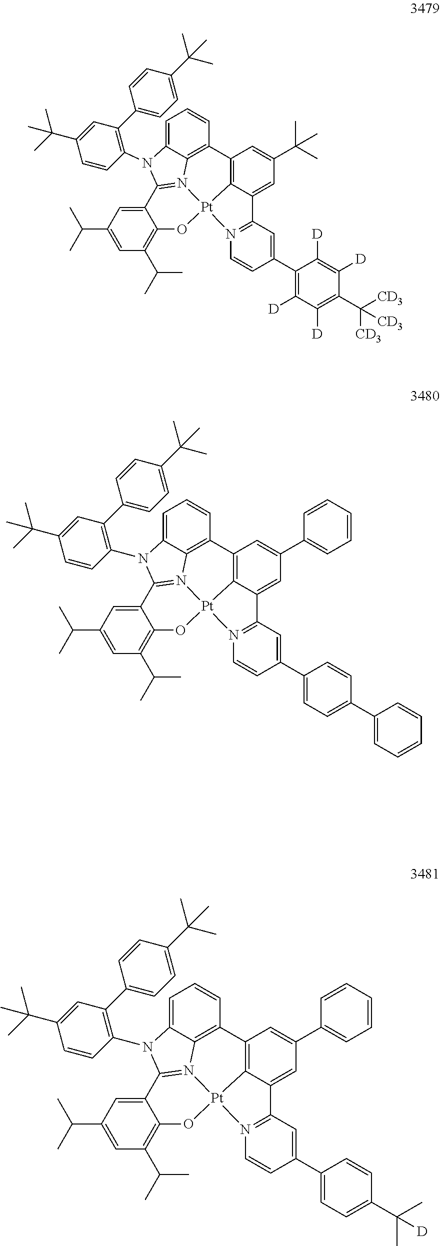

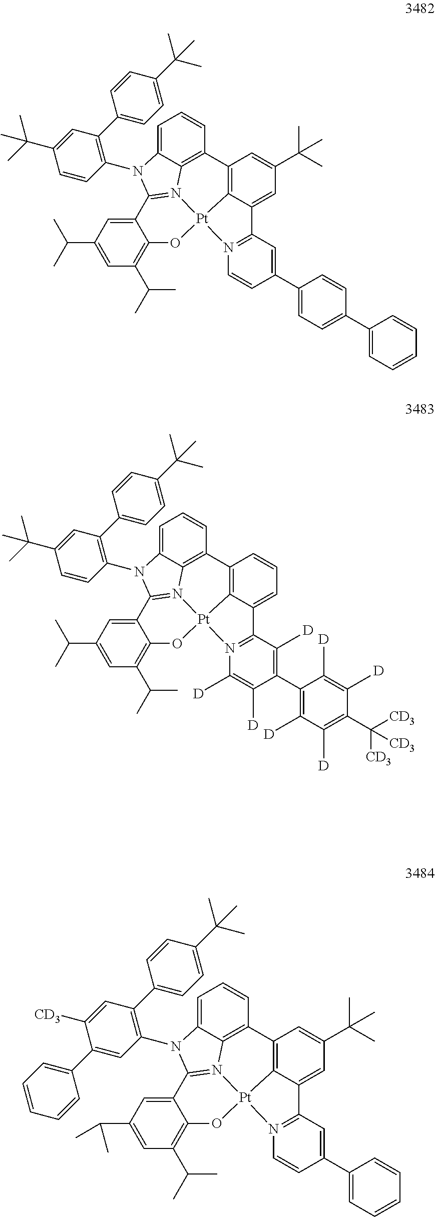

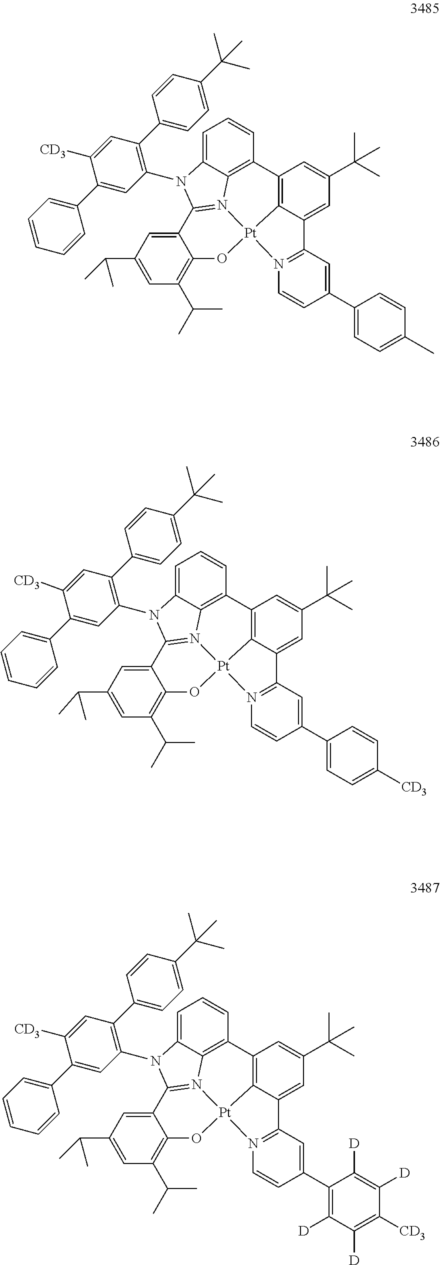

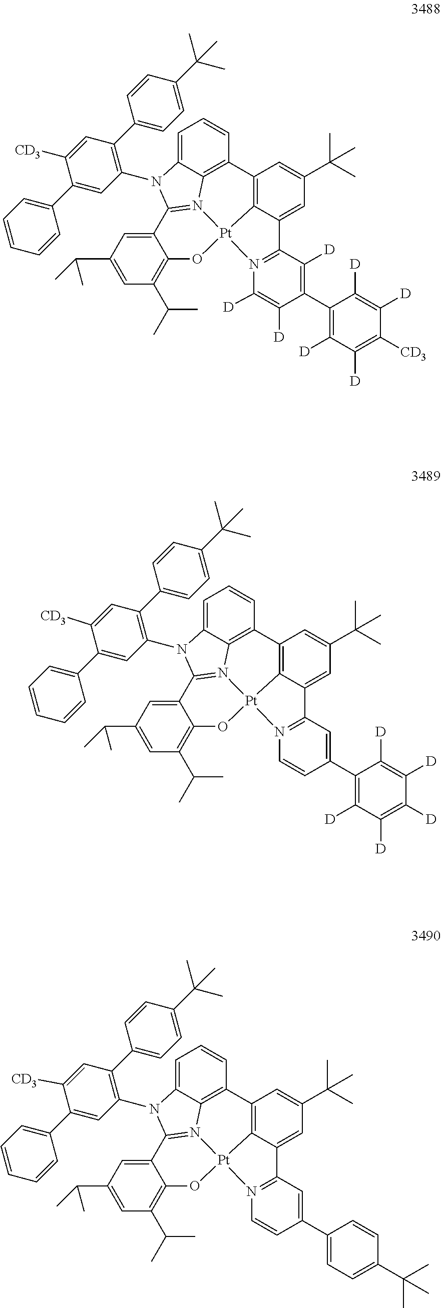

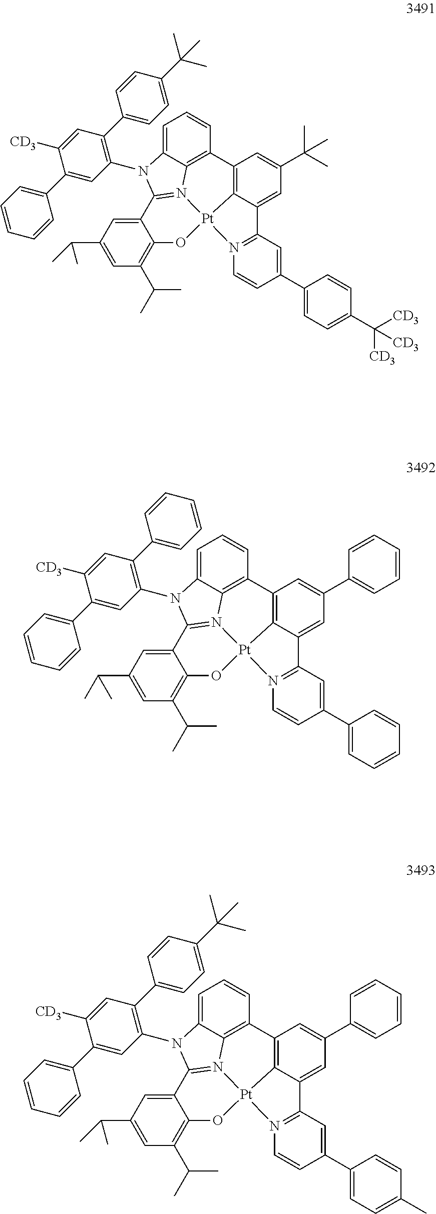

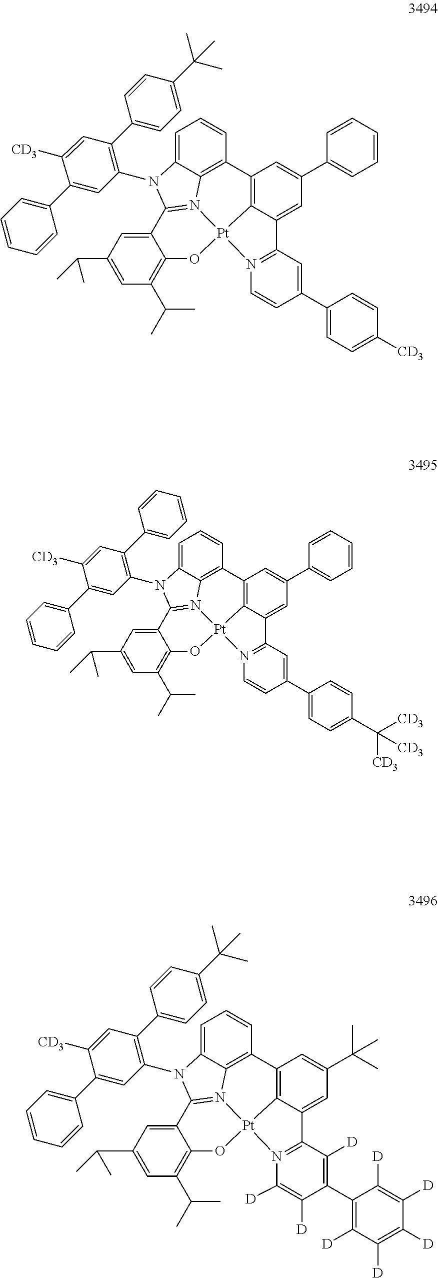

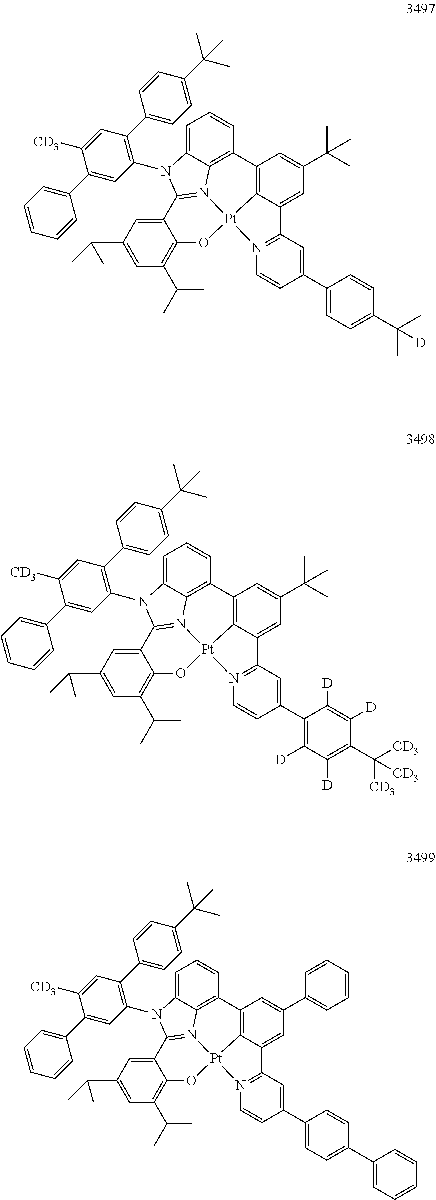

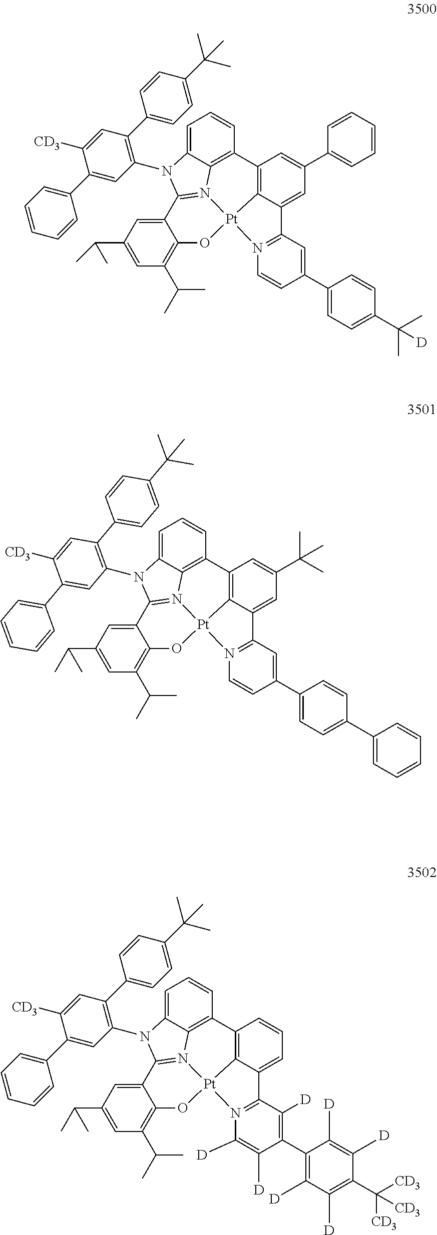

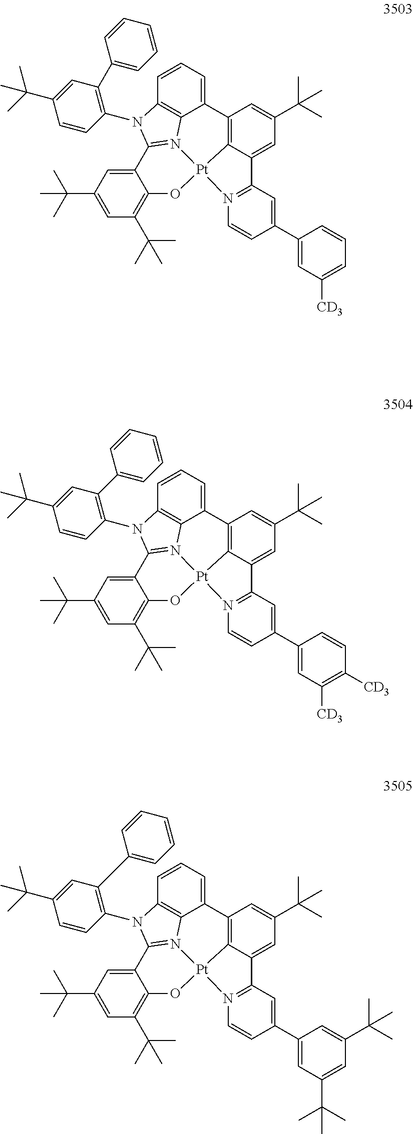

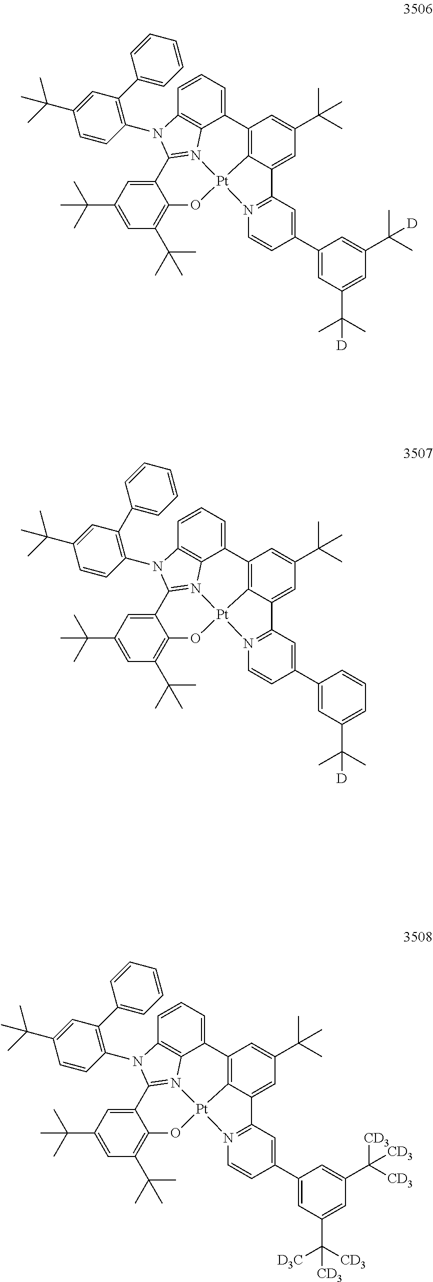

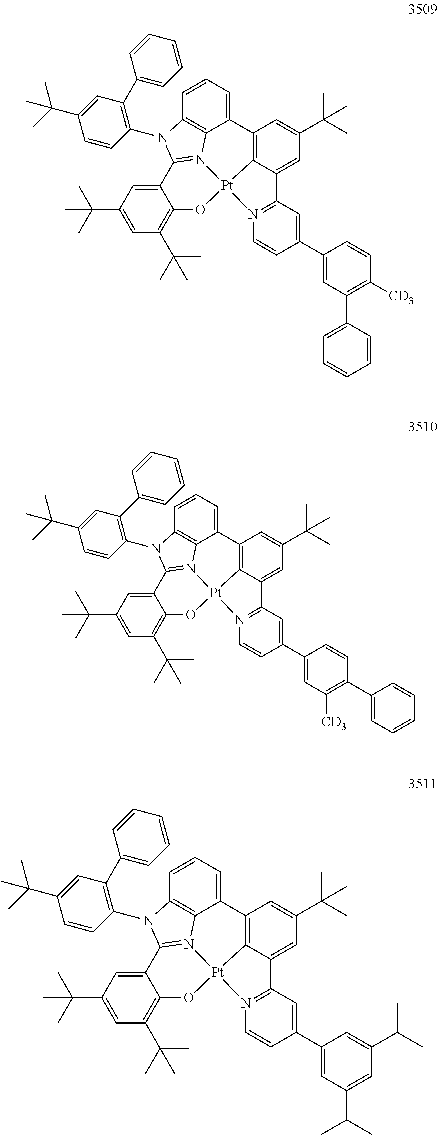

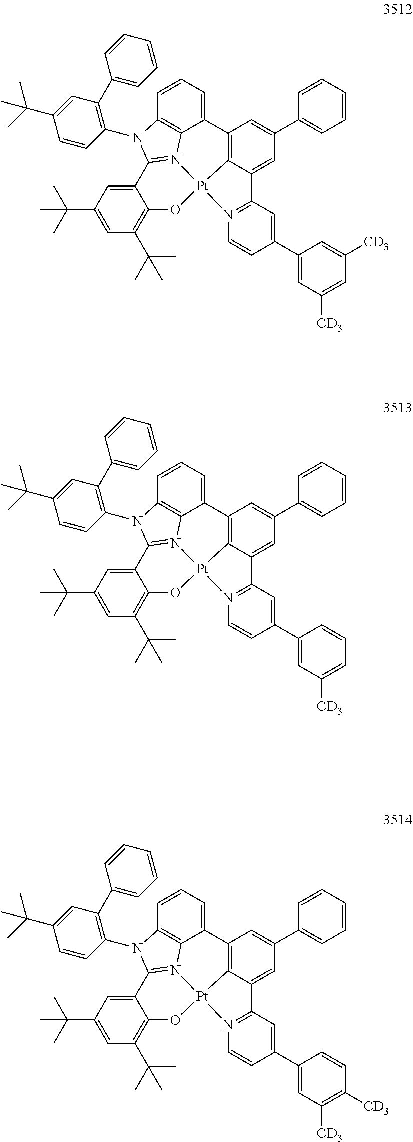

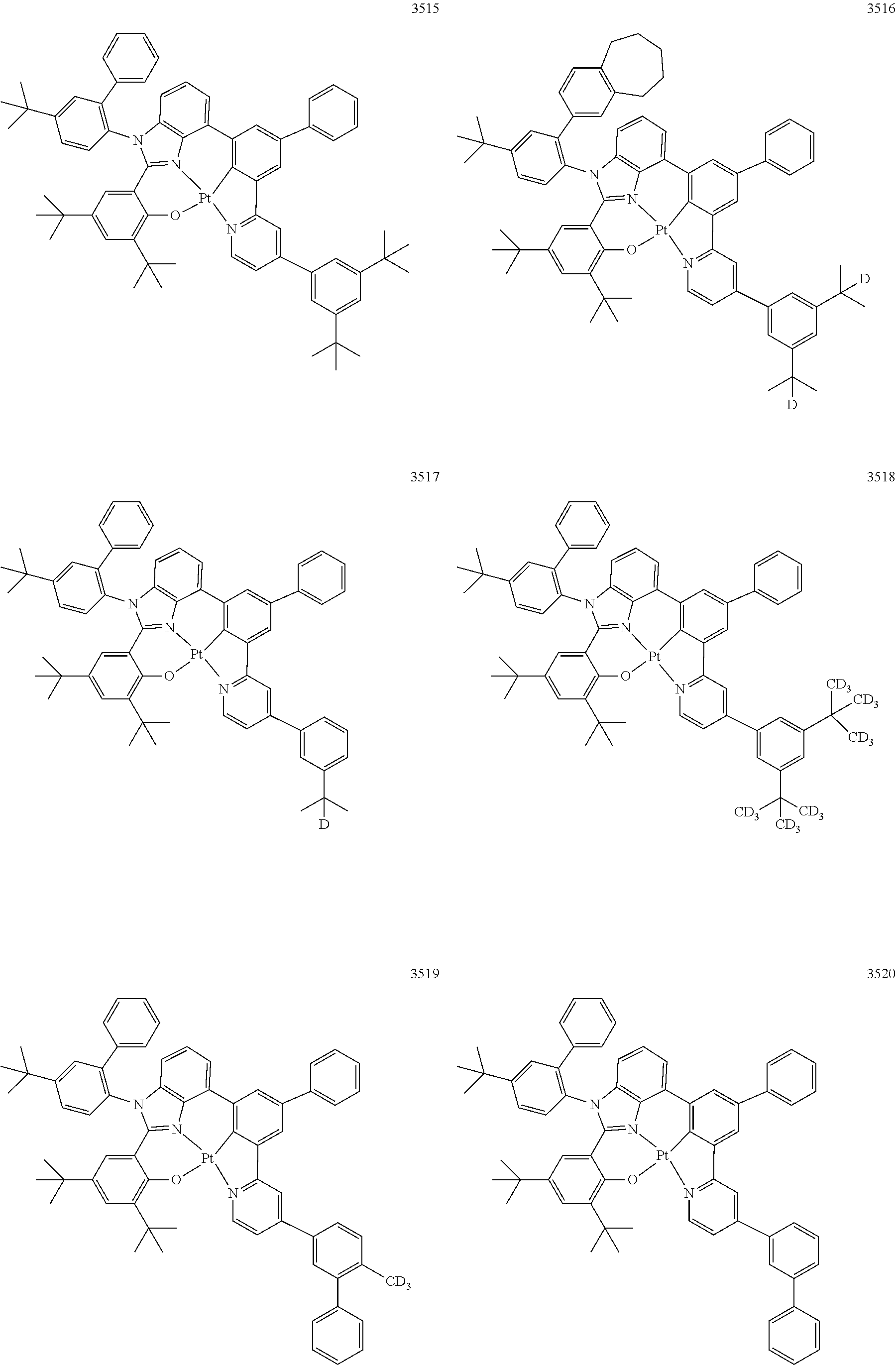

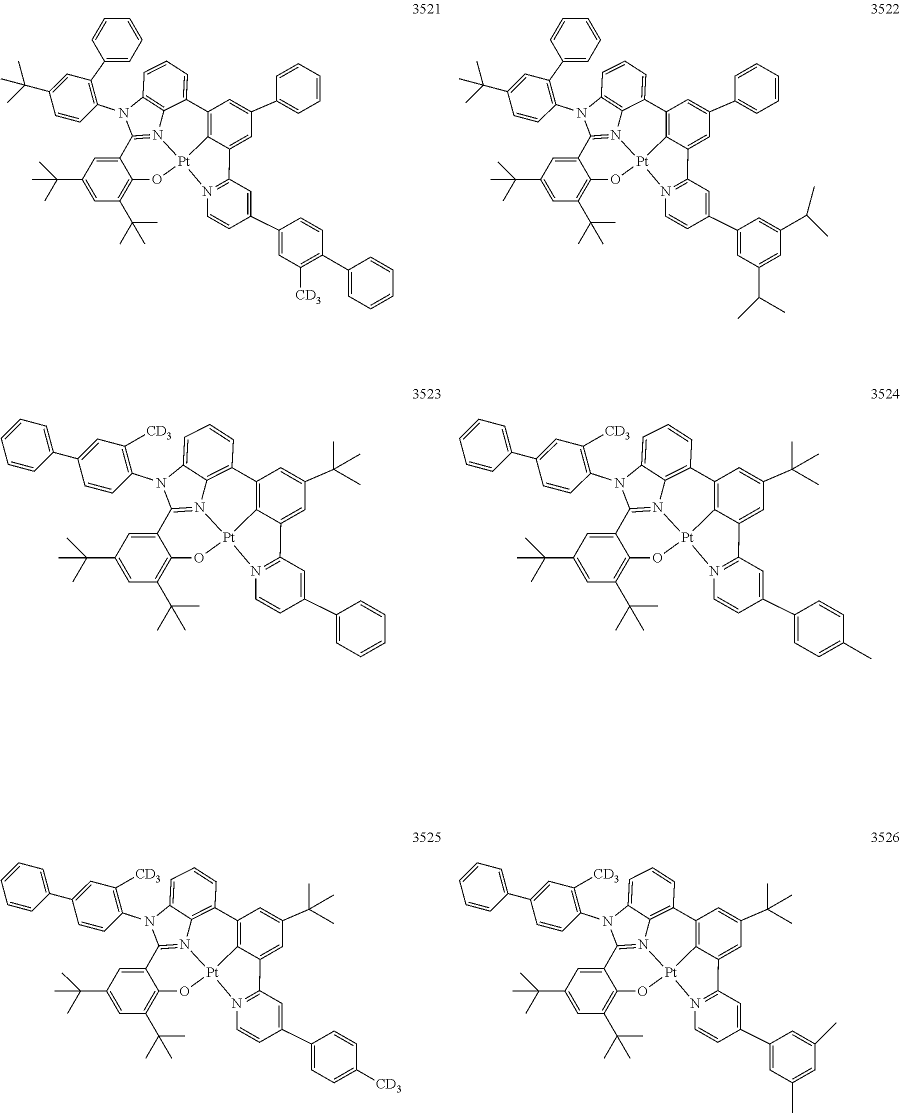

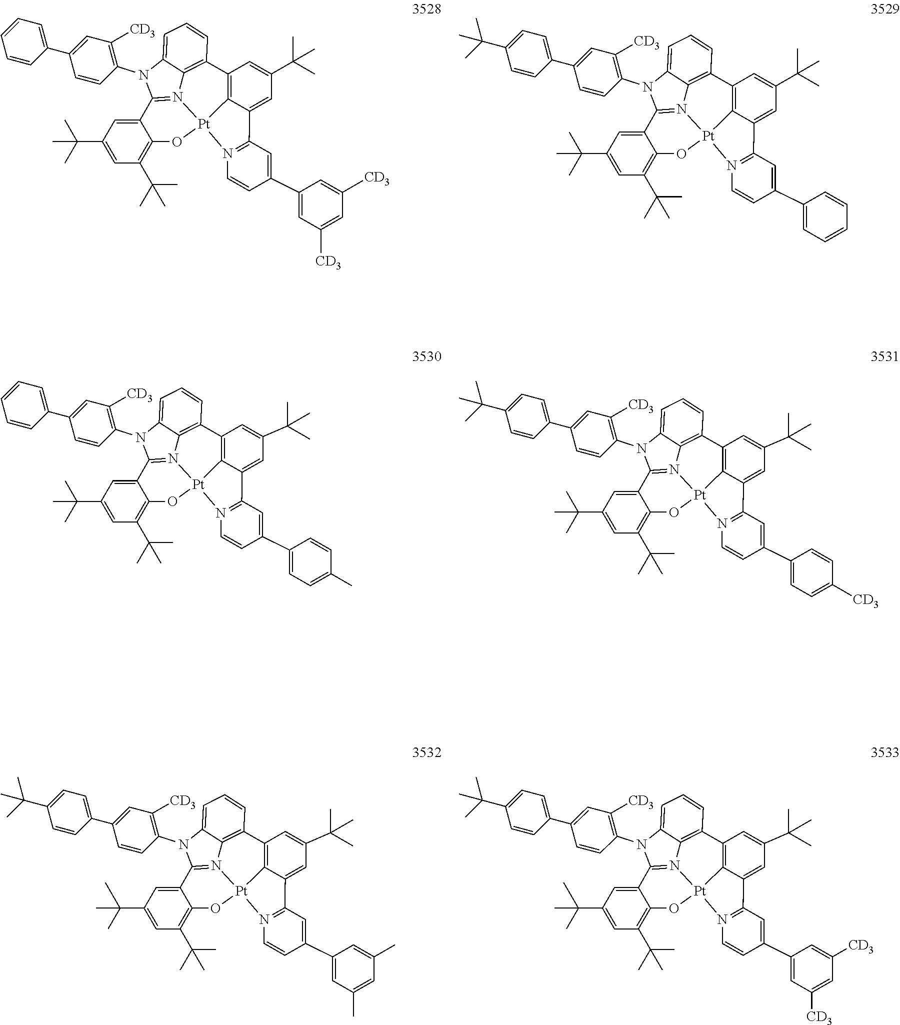

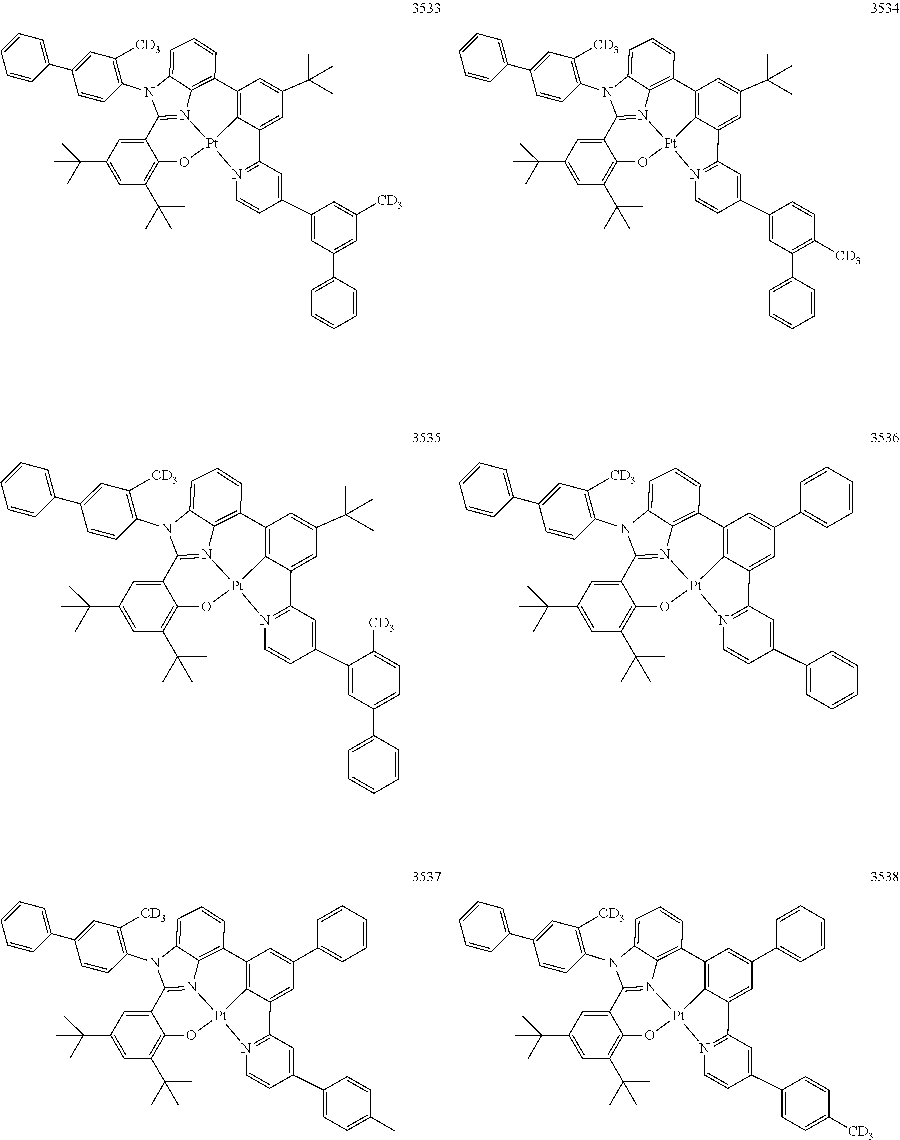

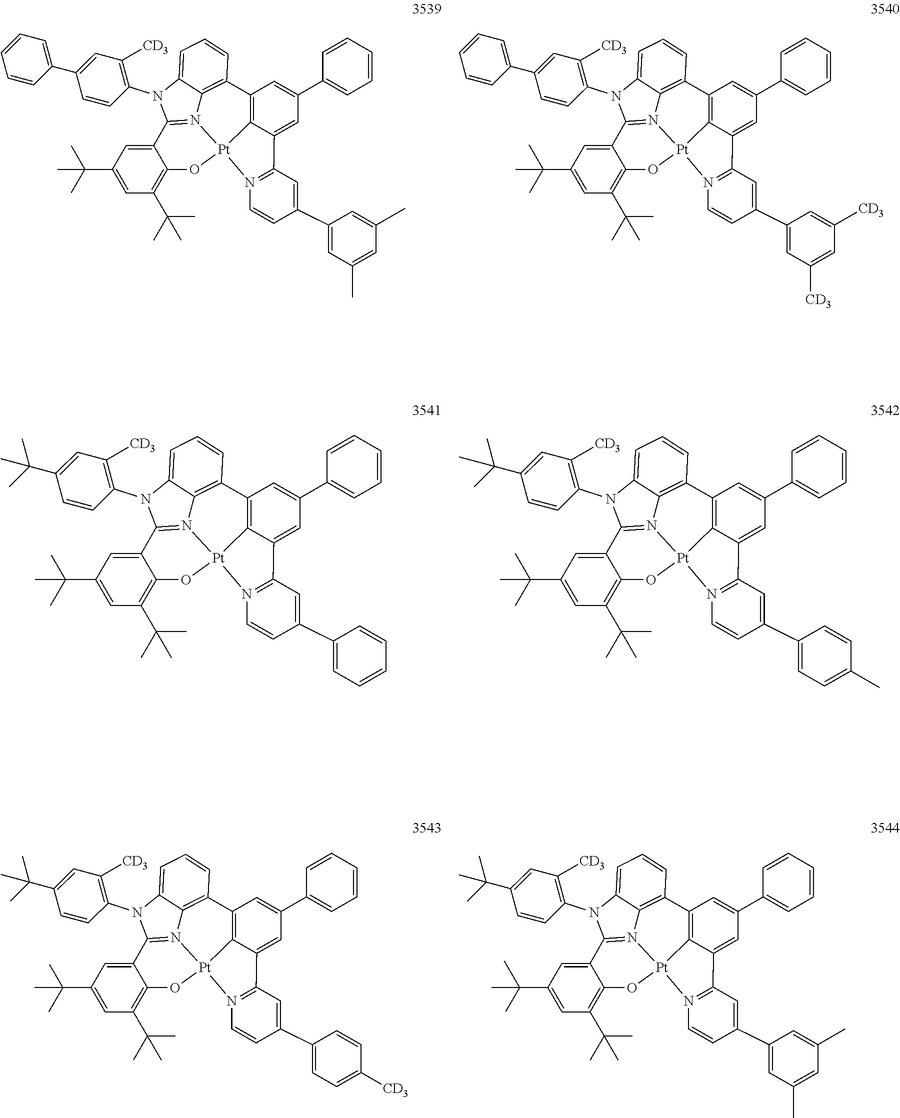

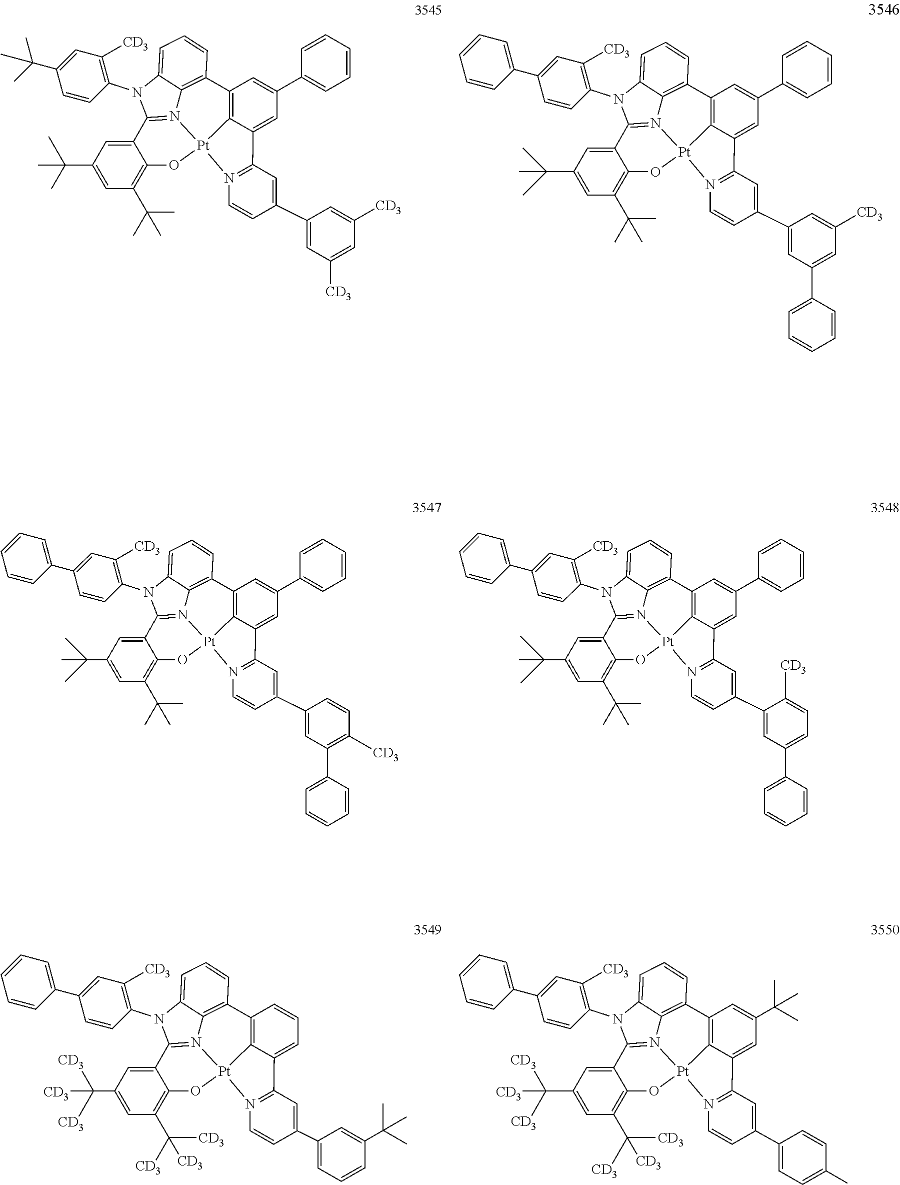

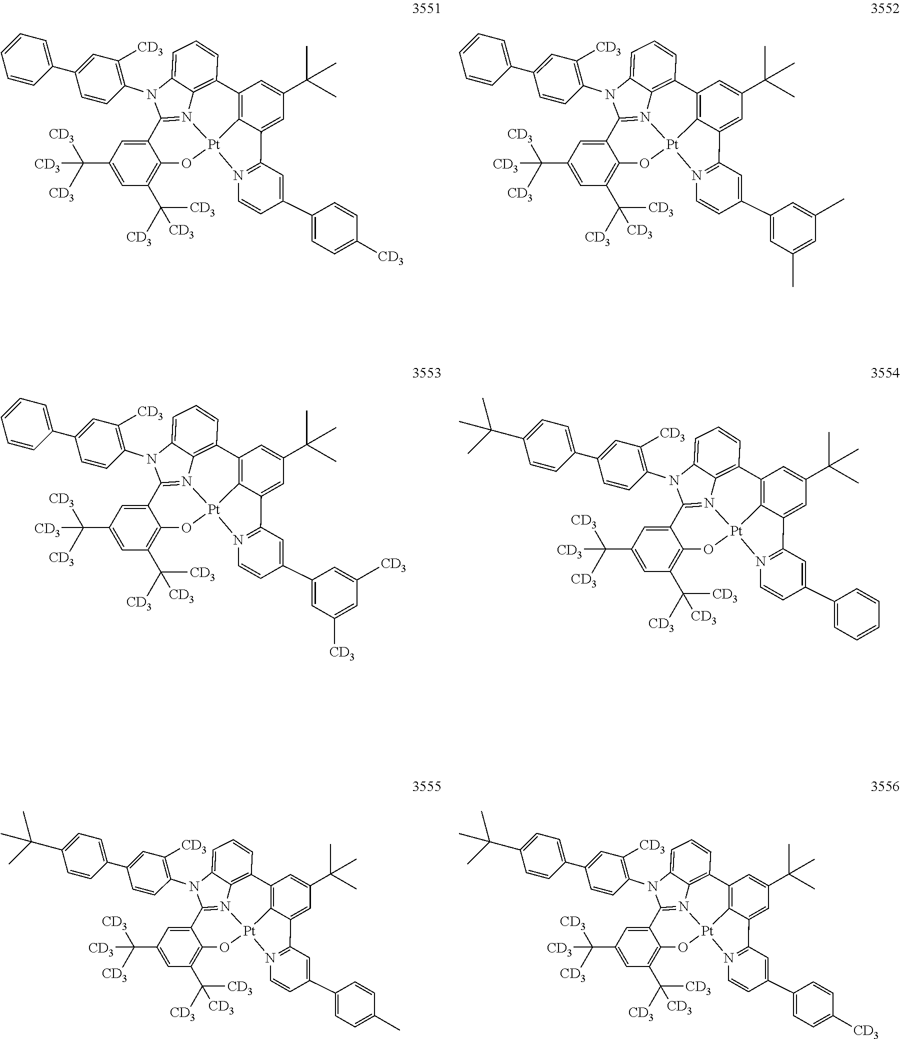

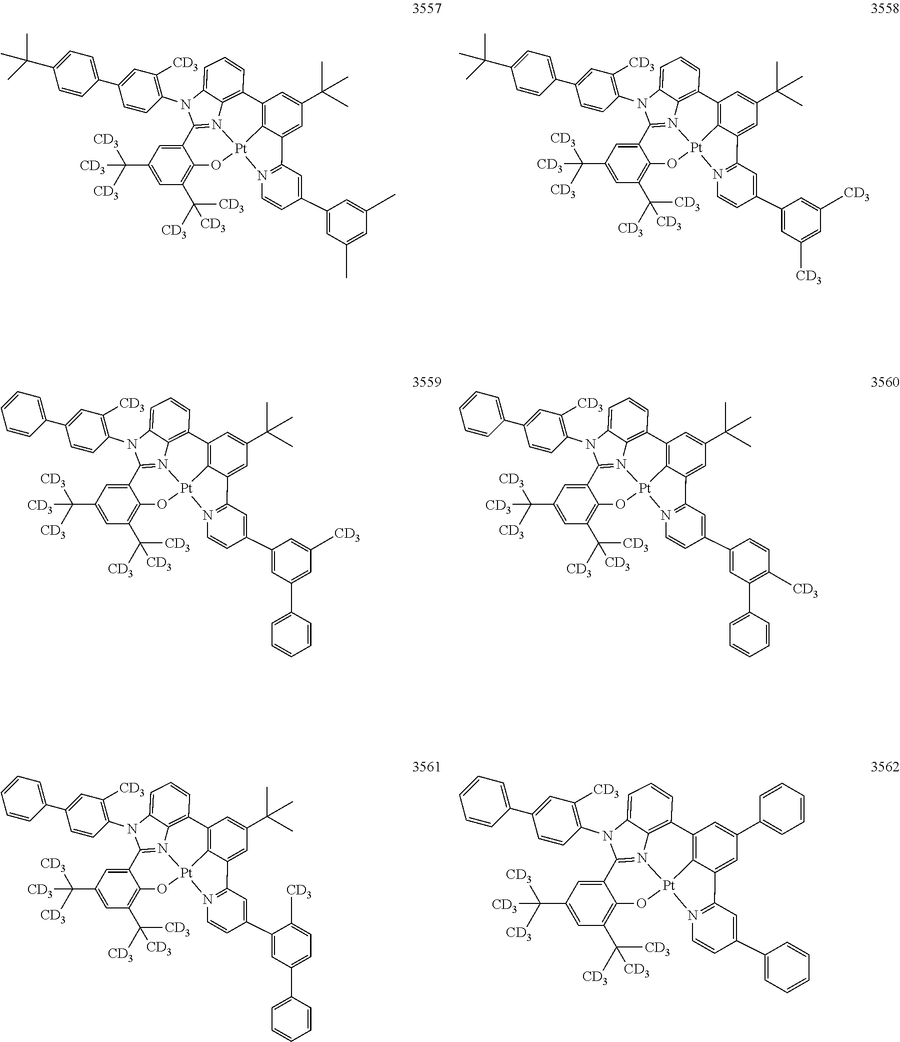

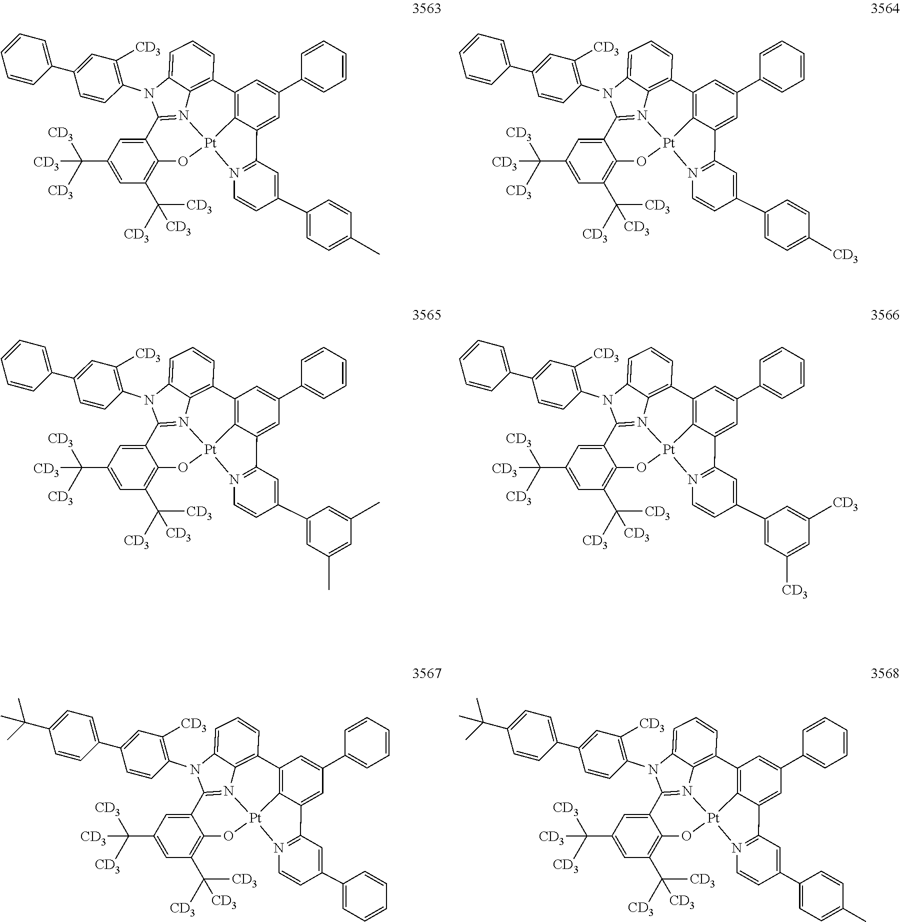

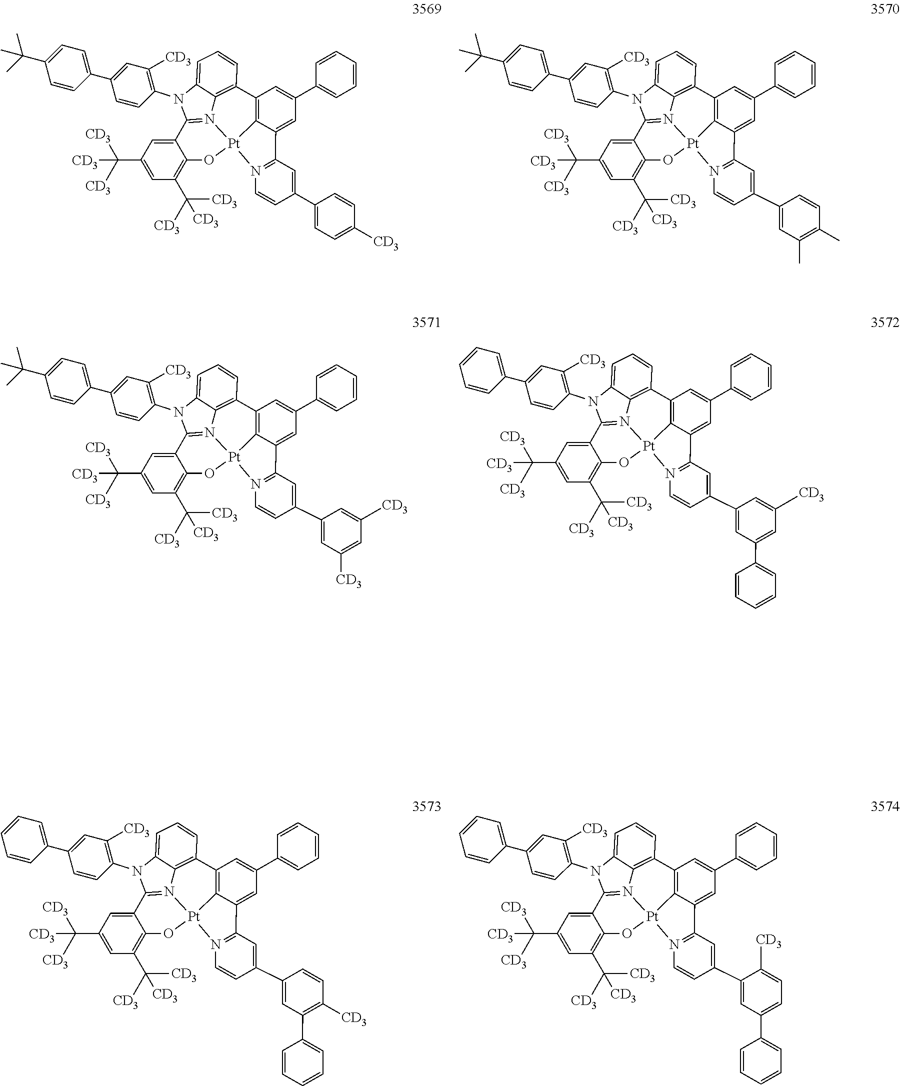

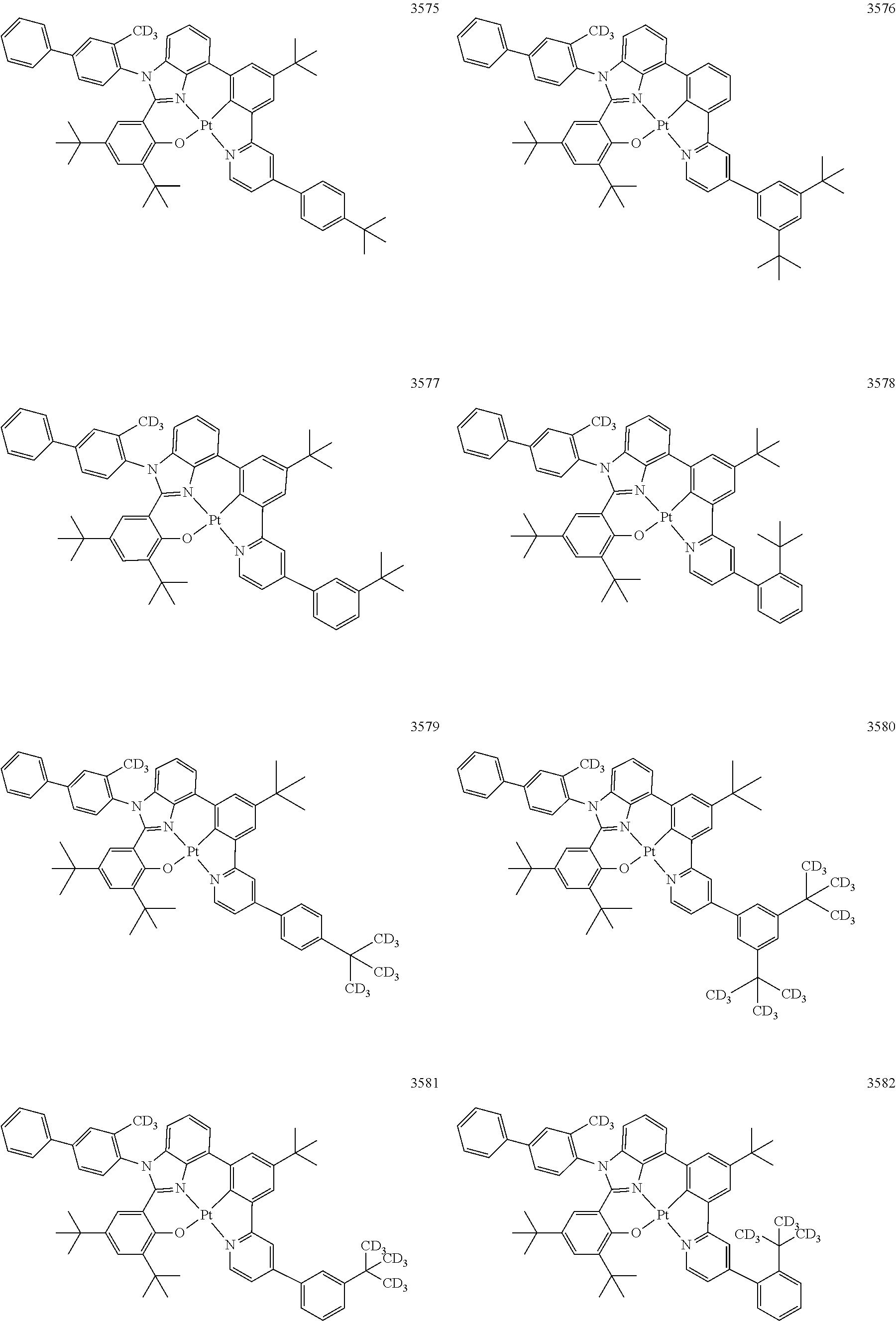

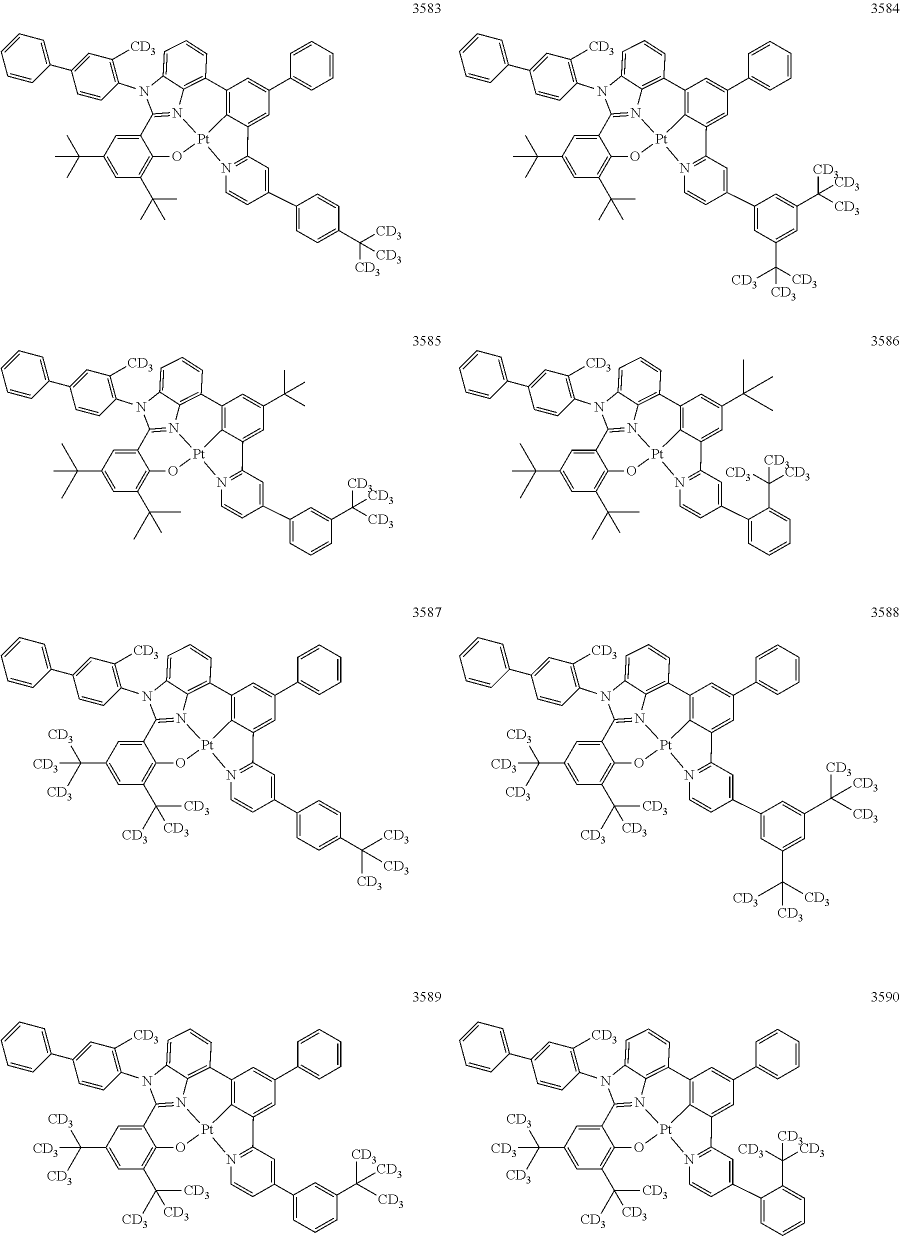

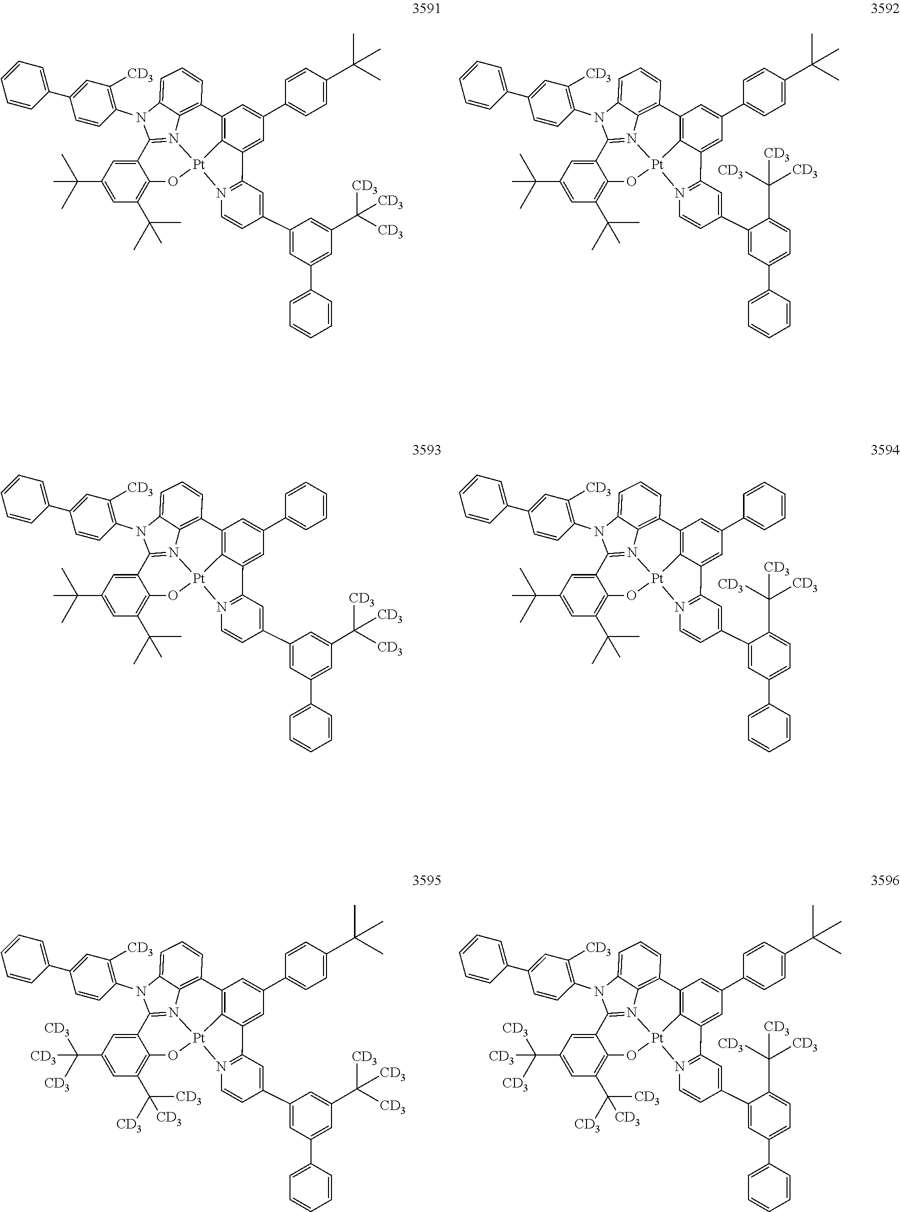

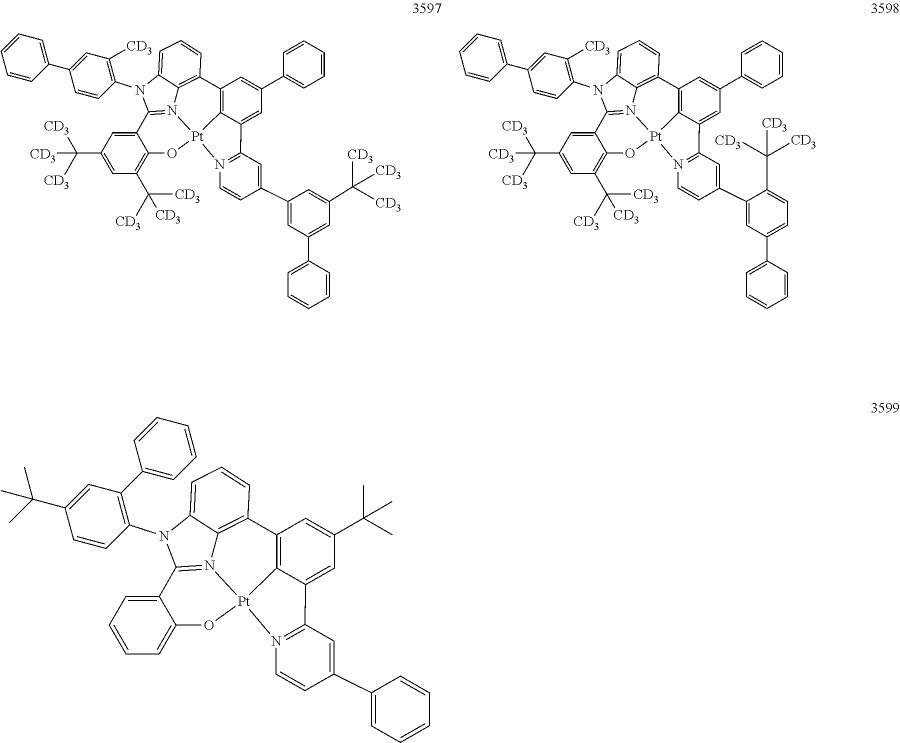

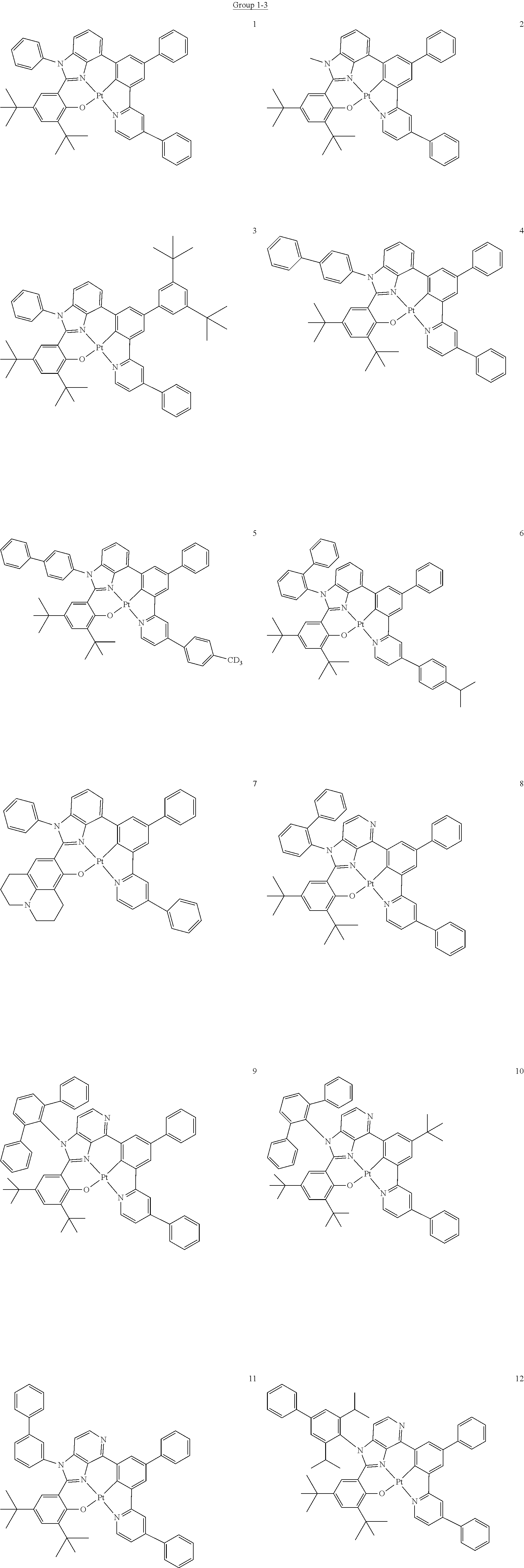

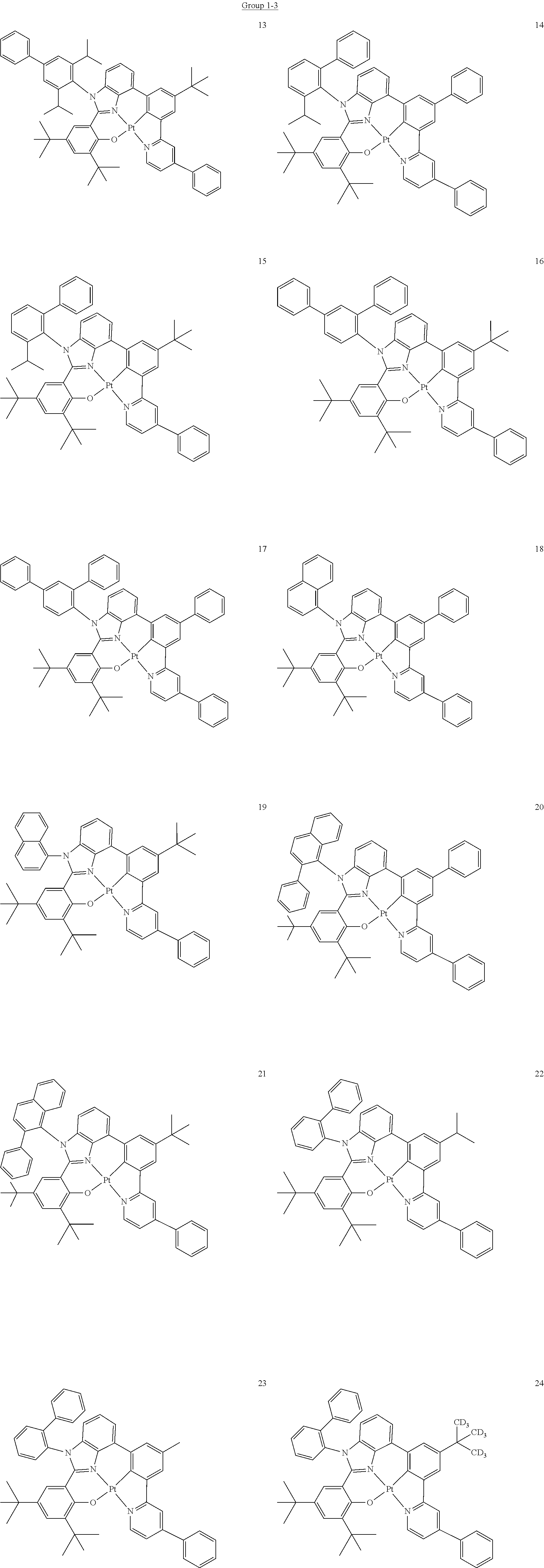

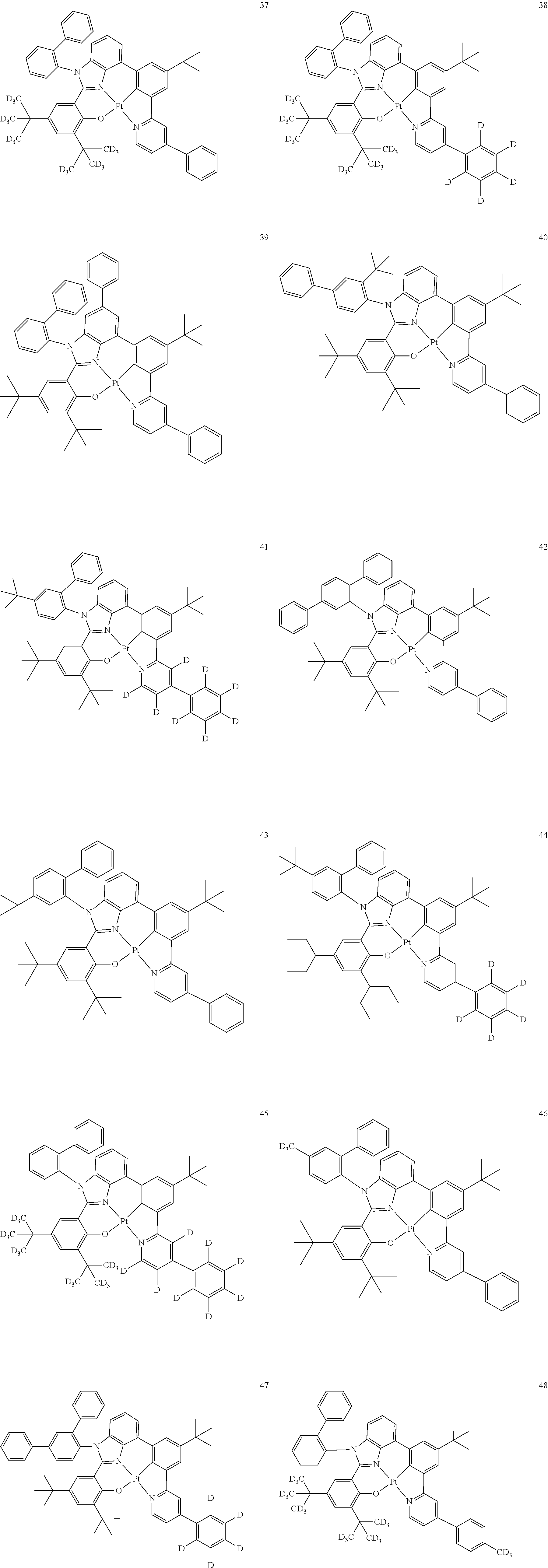

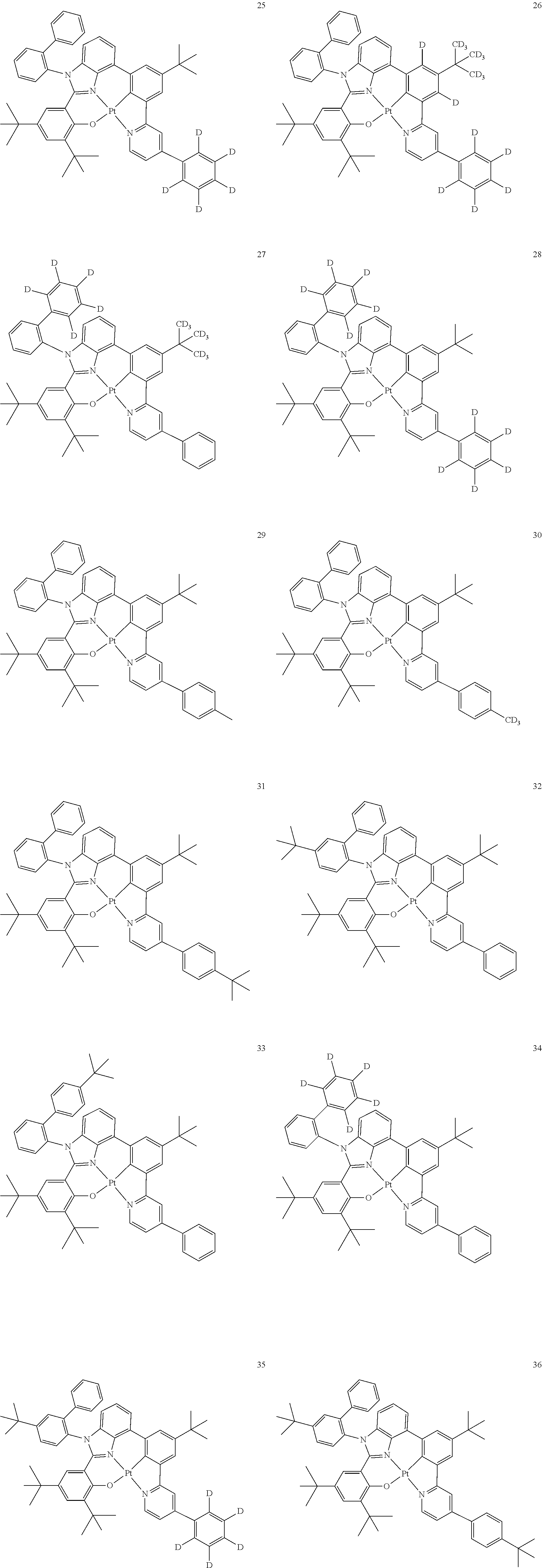

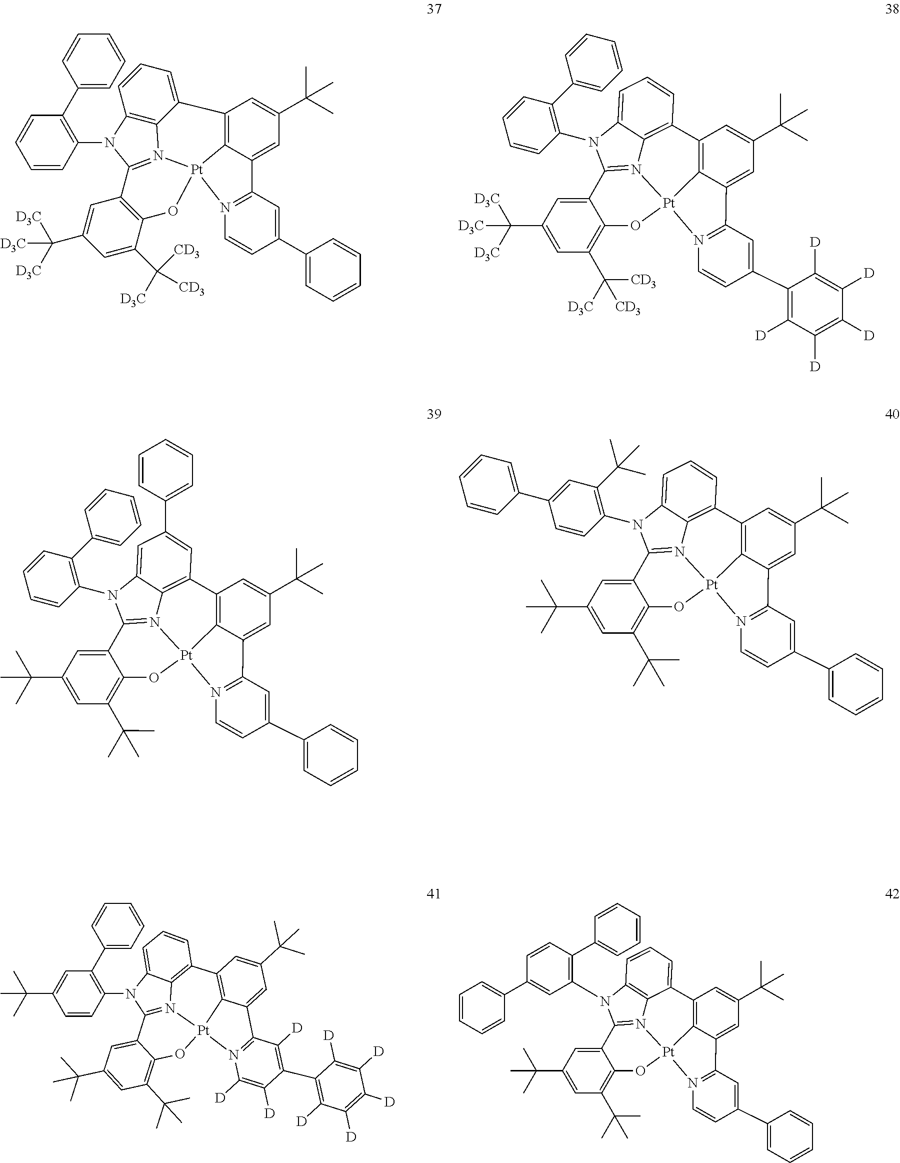

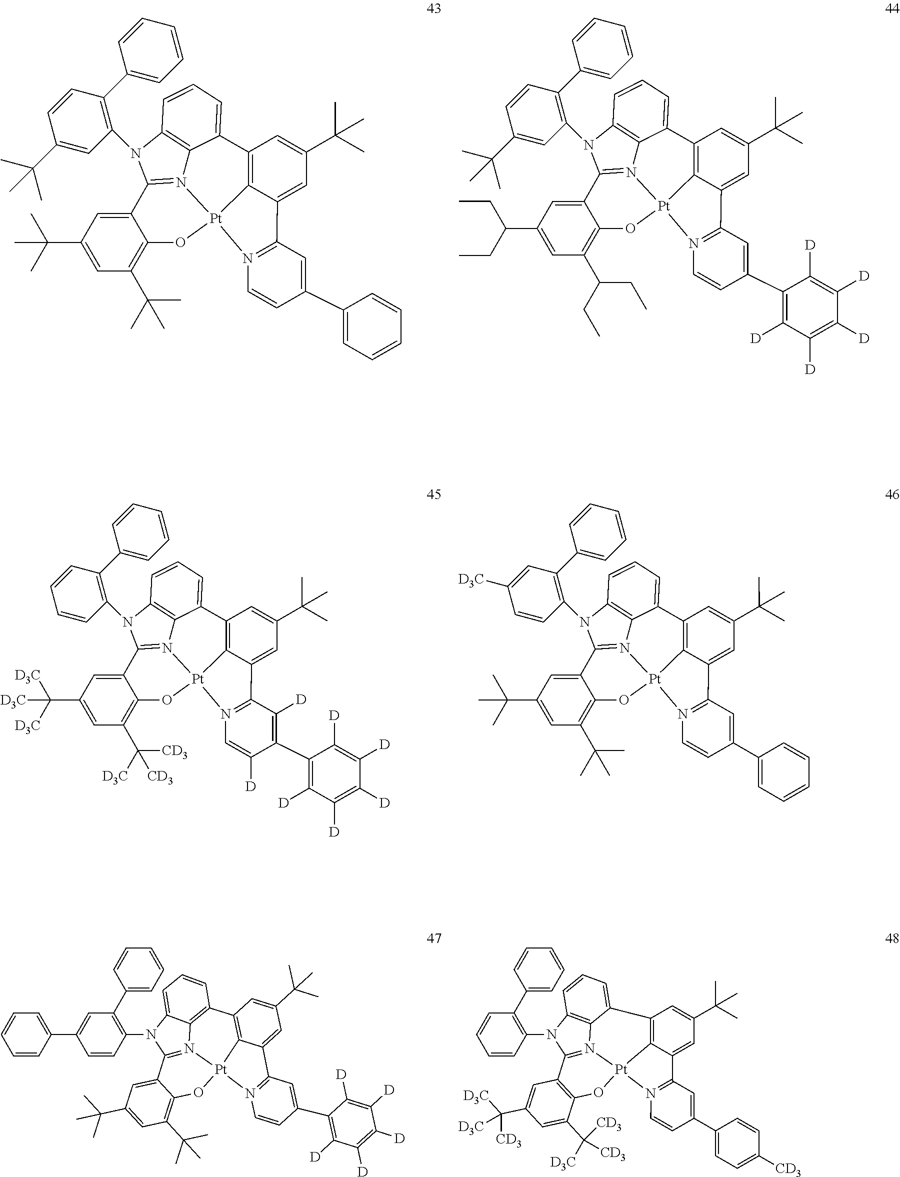

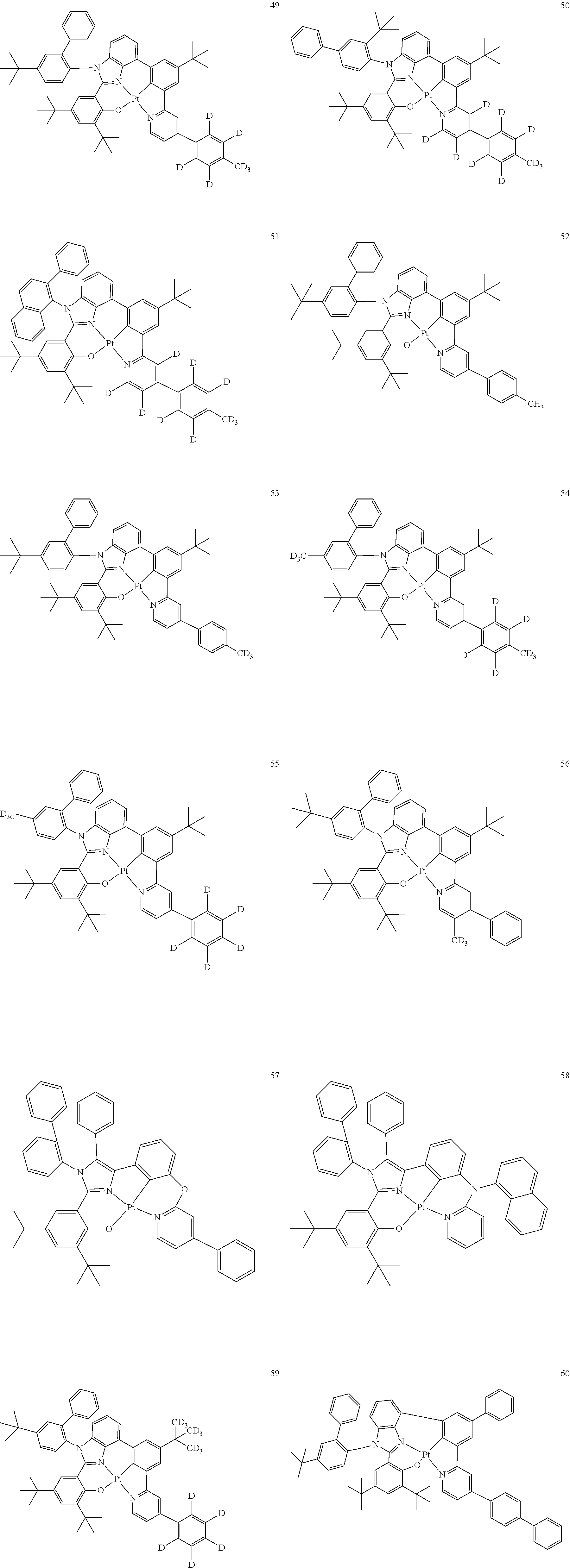

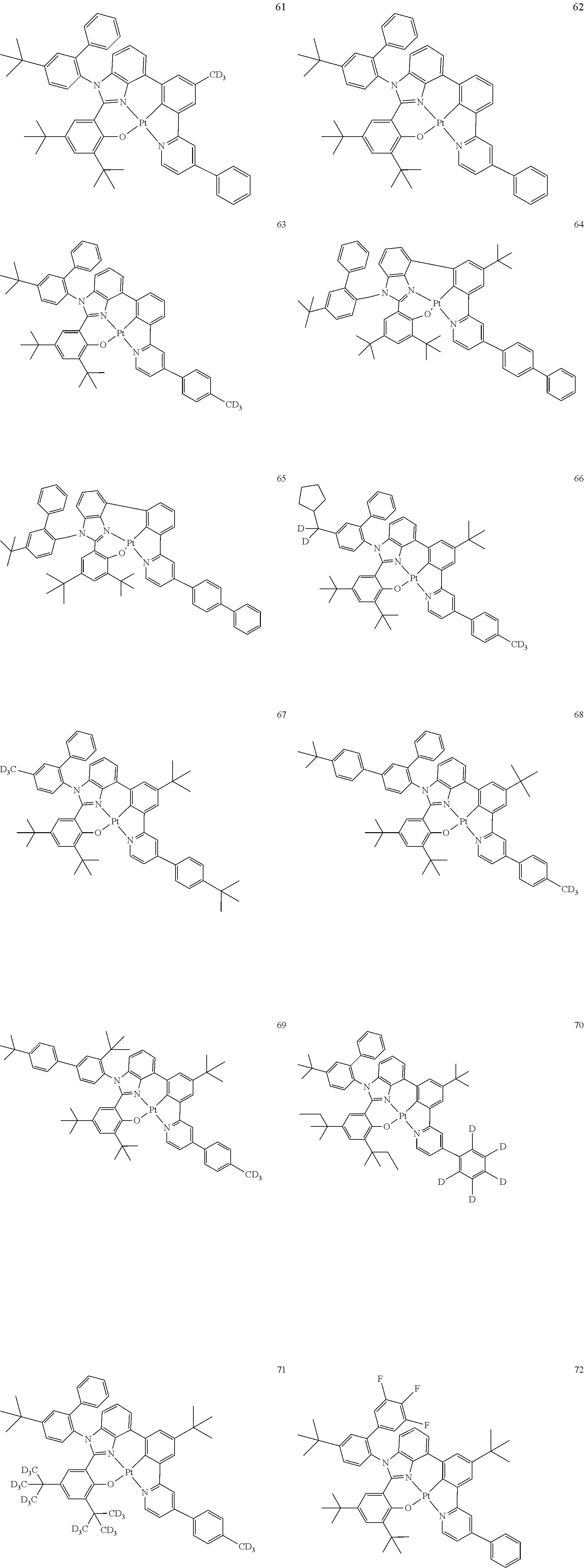

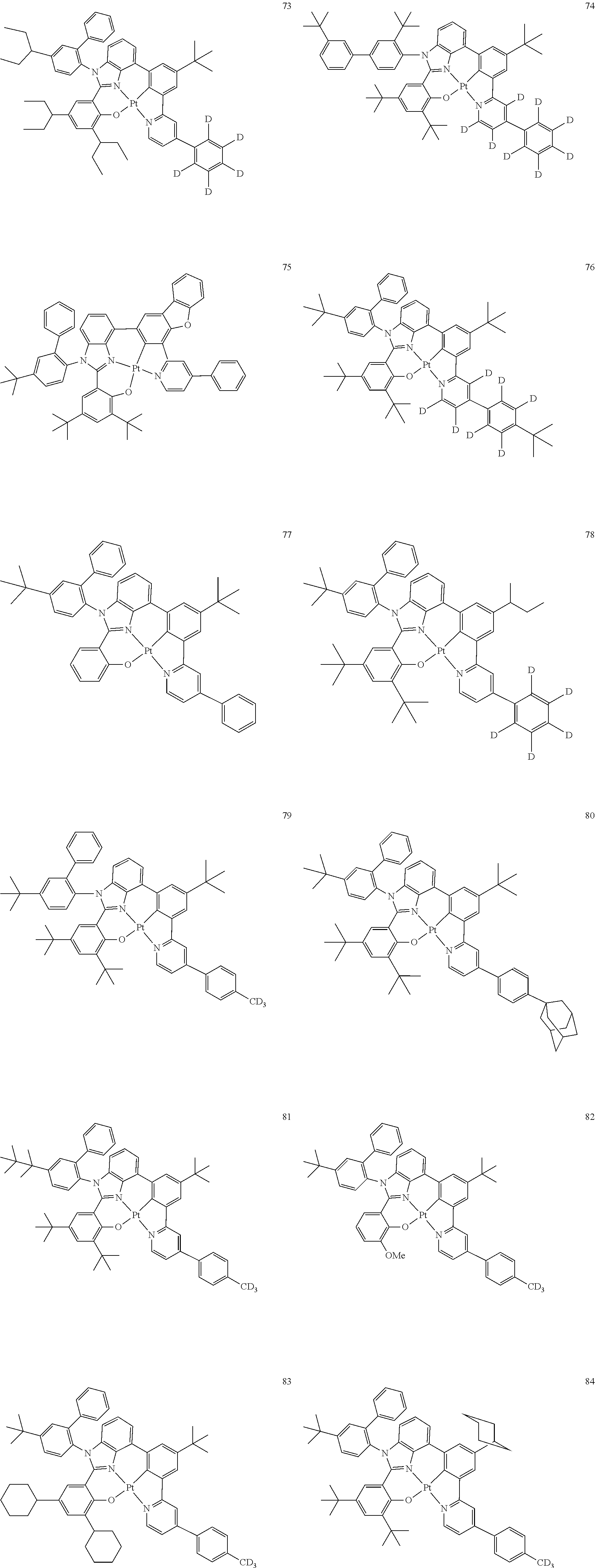

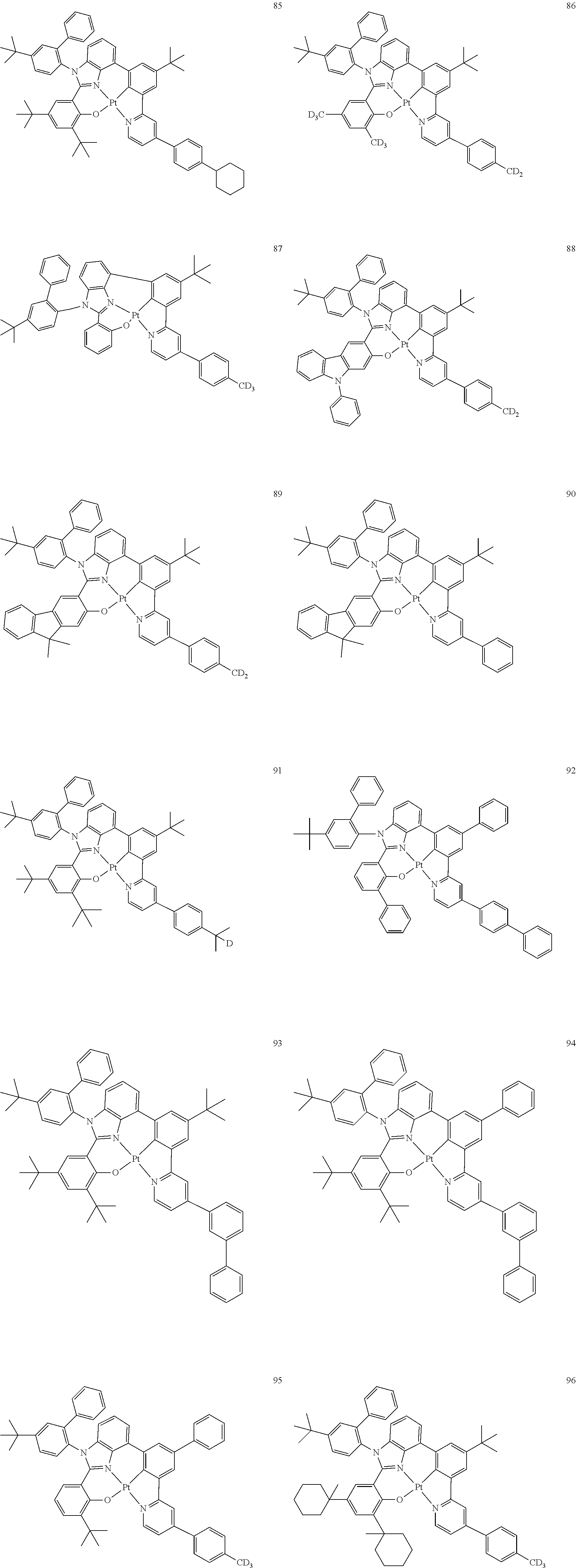

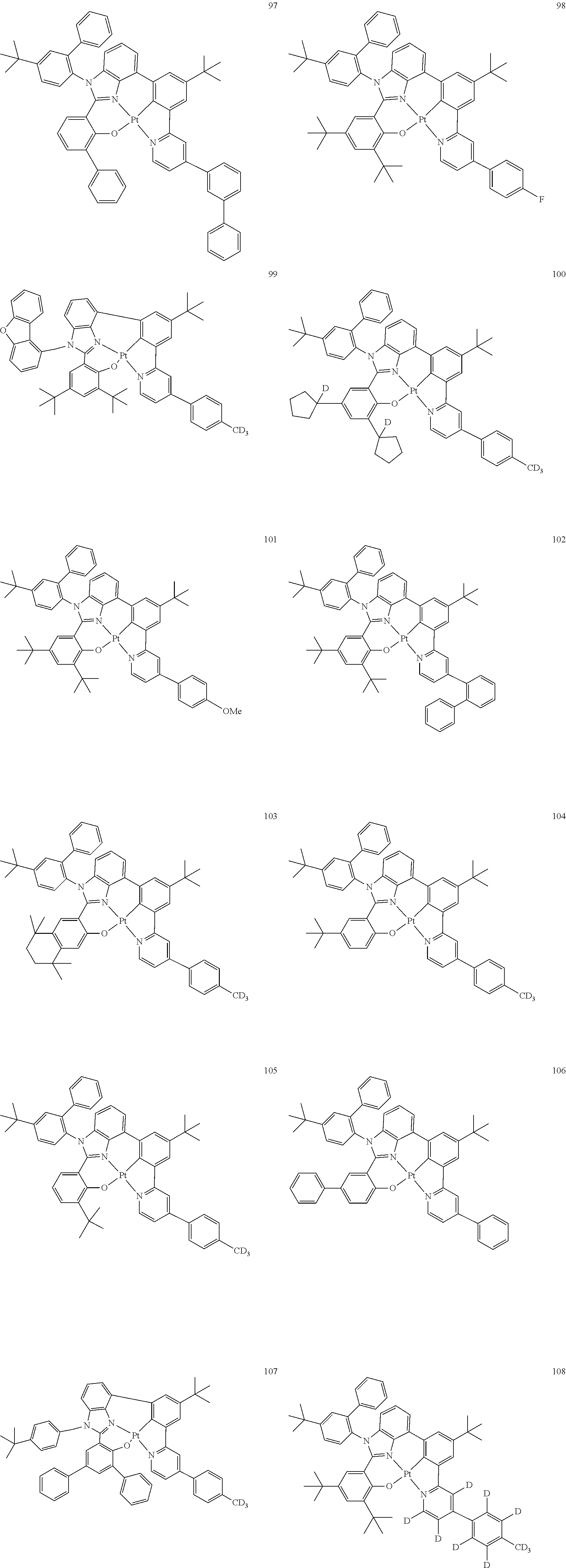

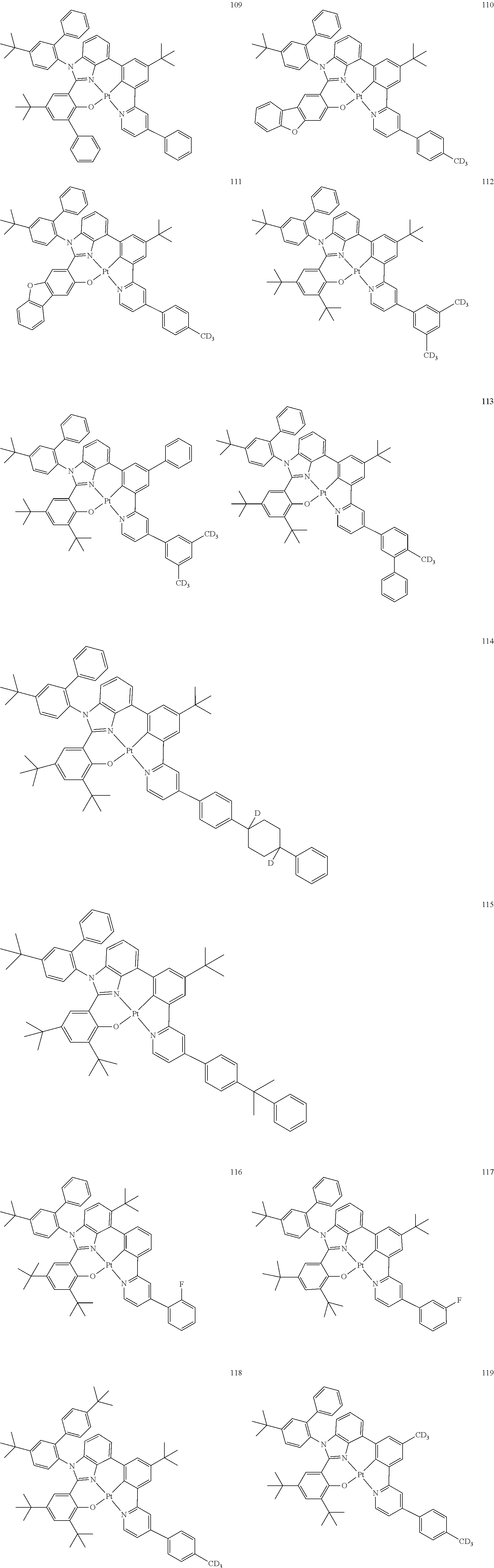

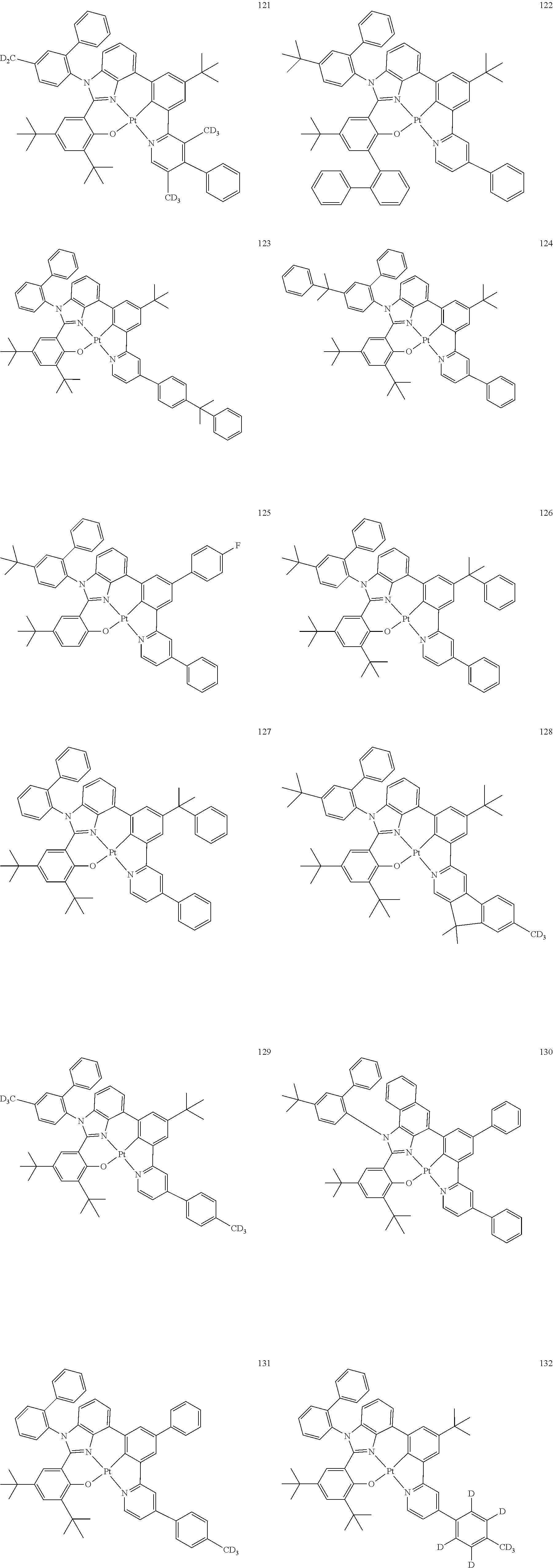

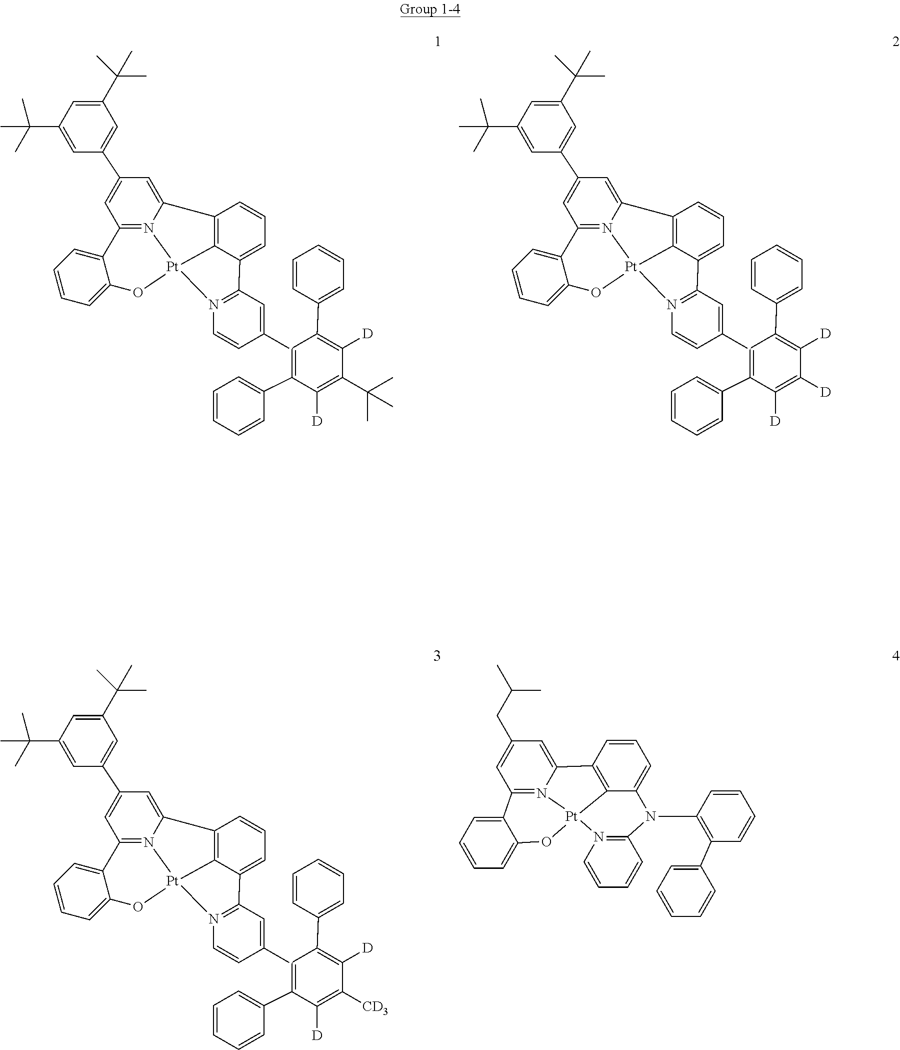

In one or more embodiments, the second compound may be a compound of Group 2-1 to Group 2-5:

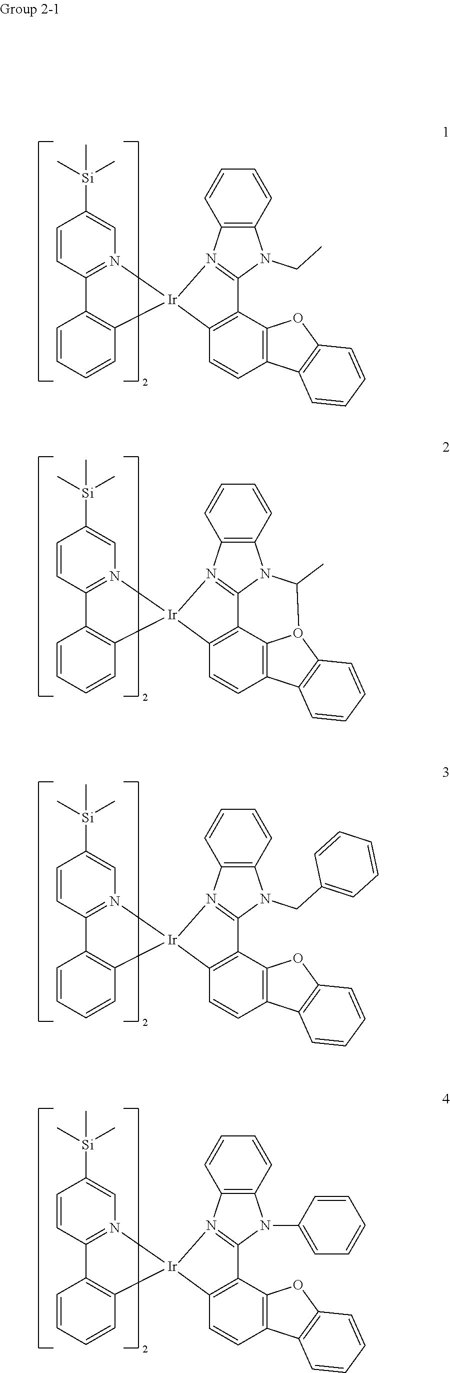

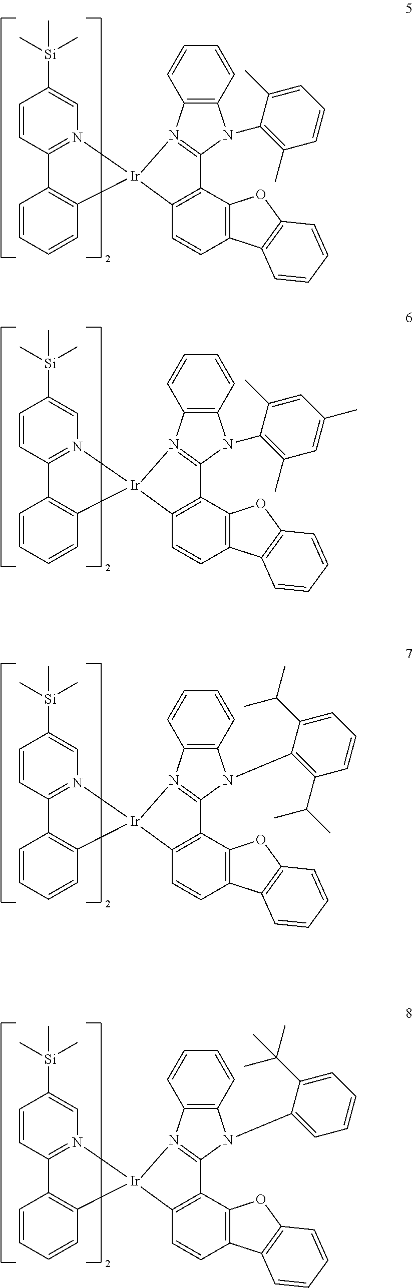

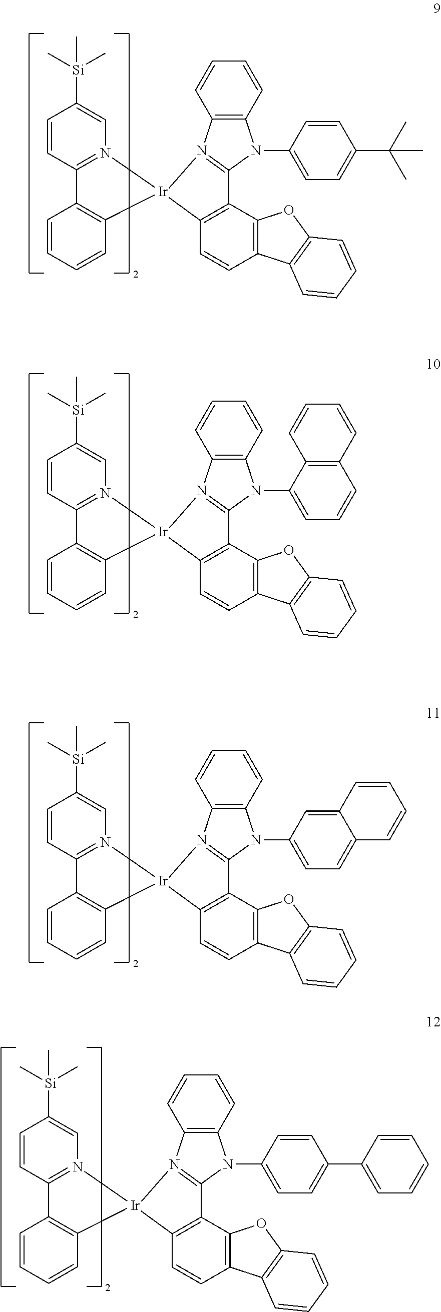

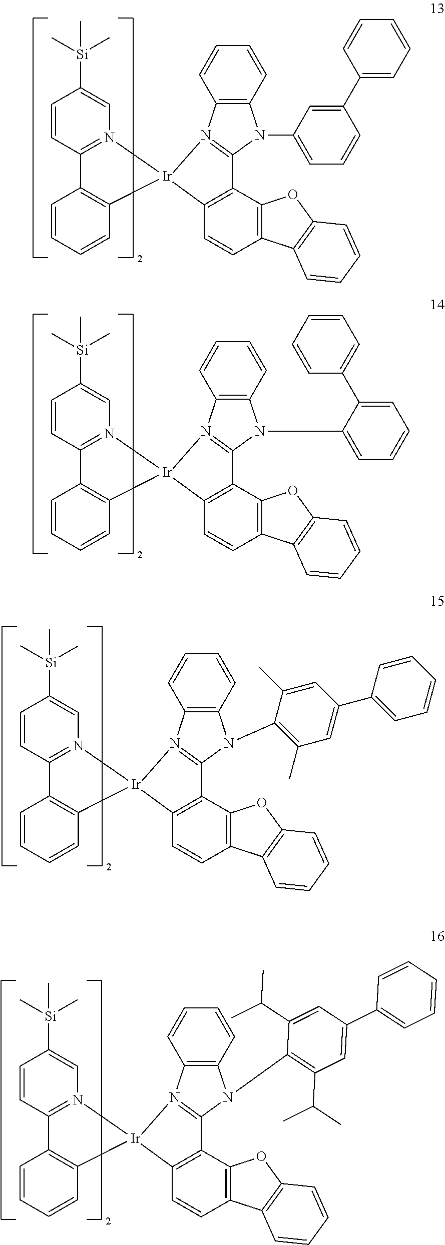

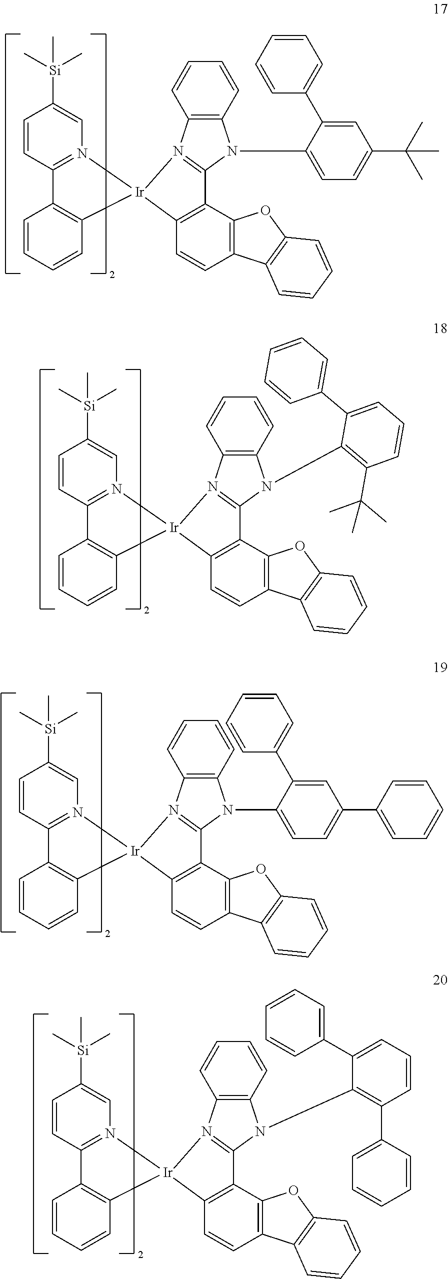

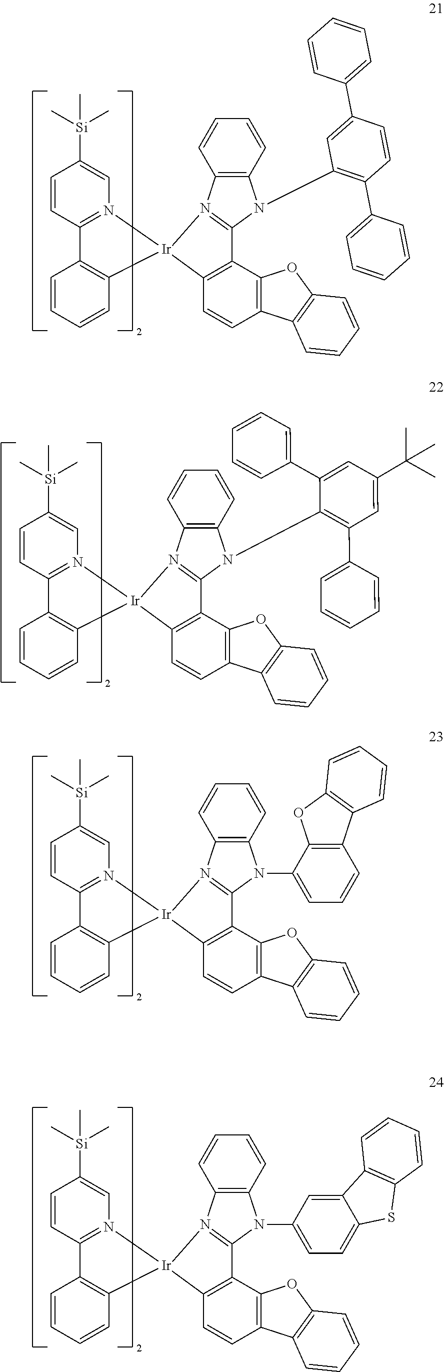

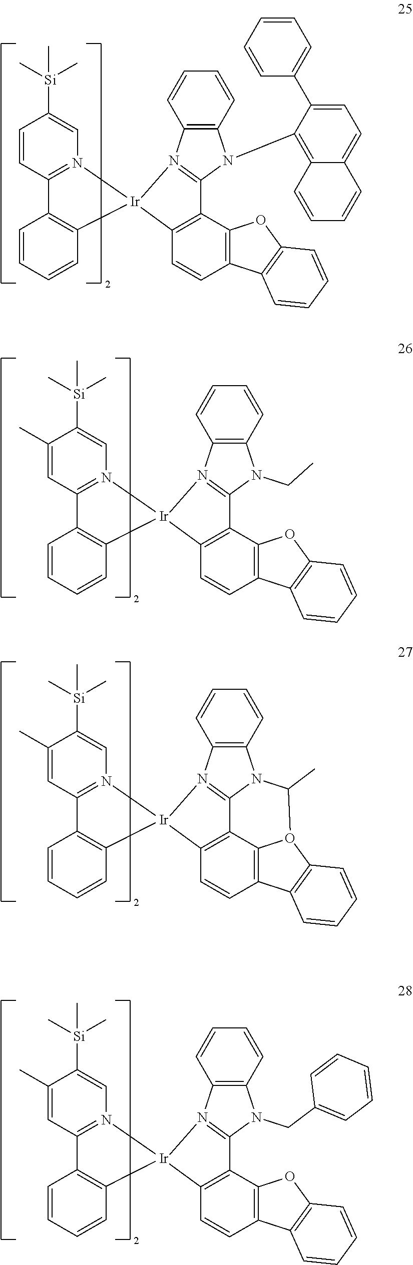

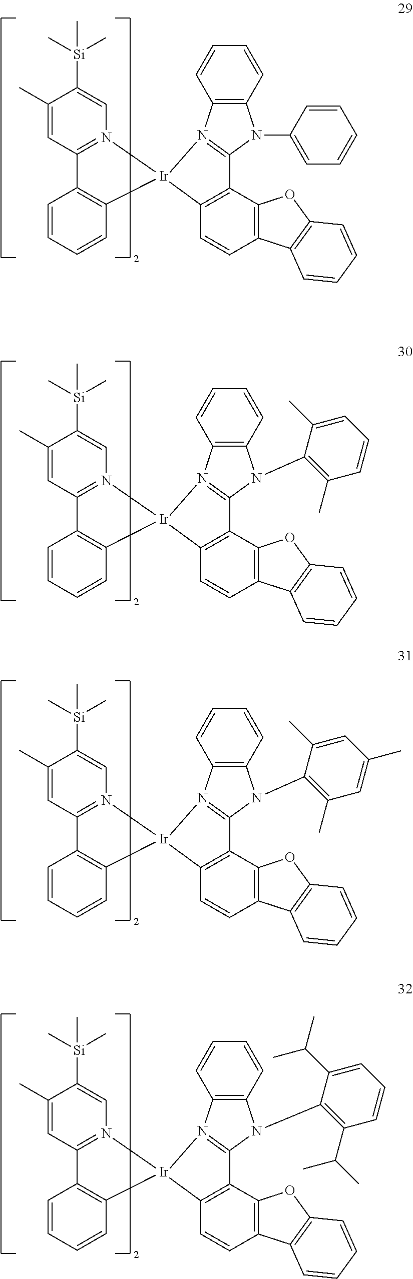

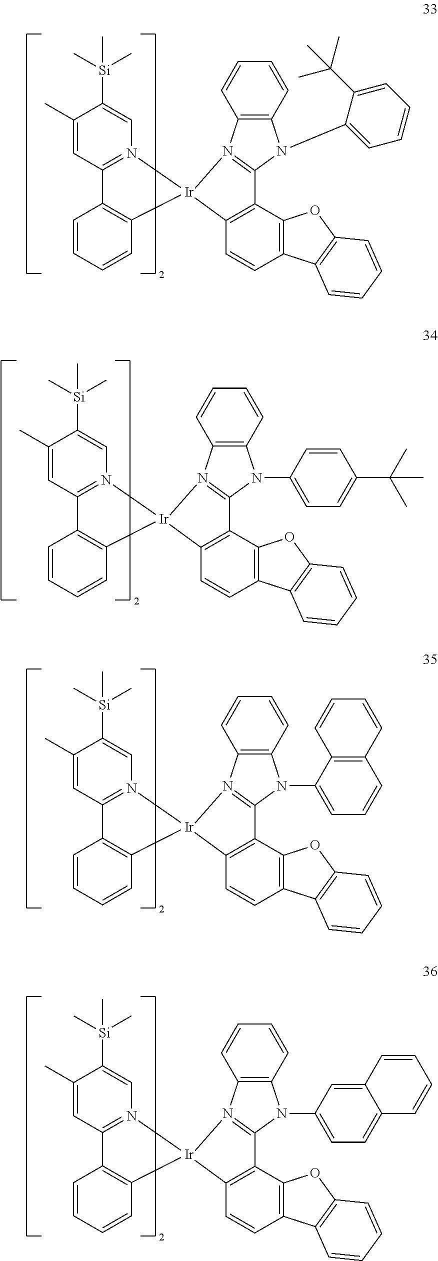

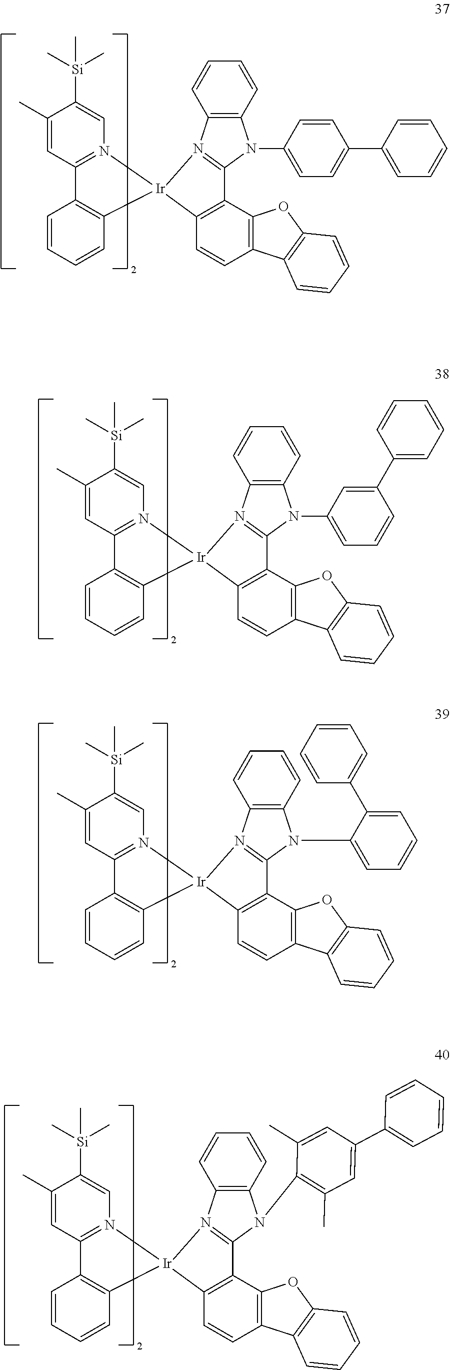

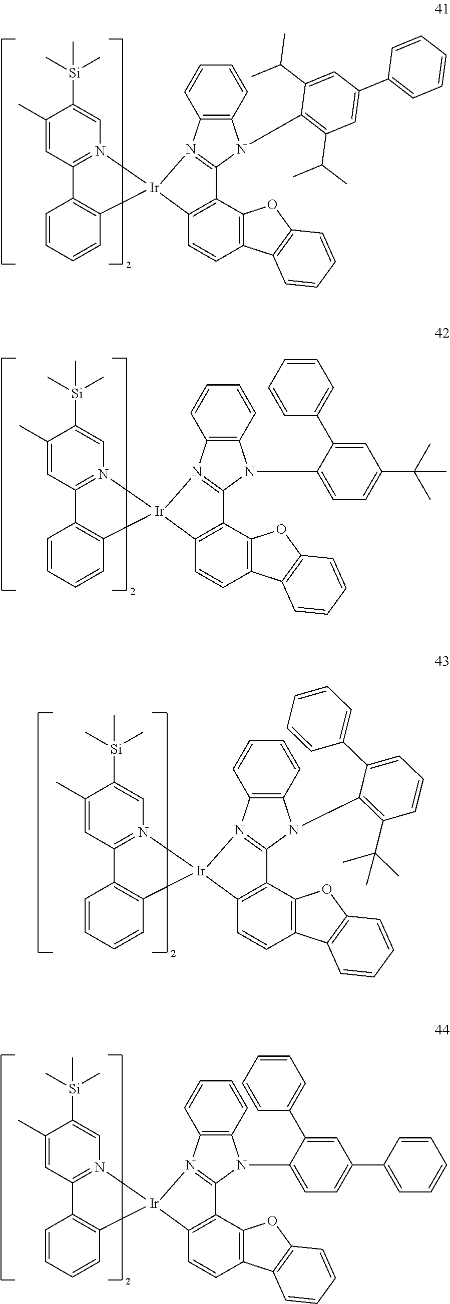

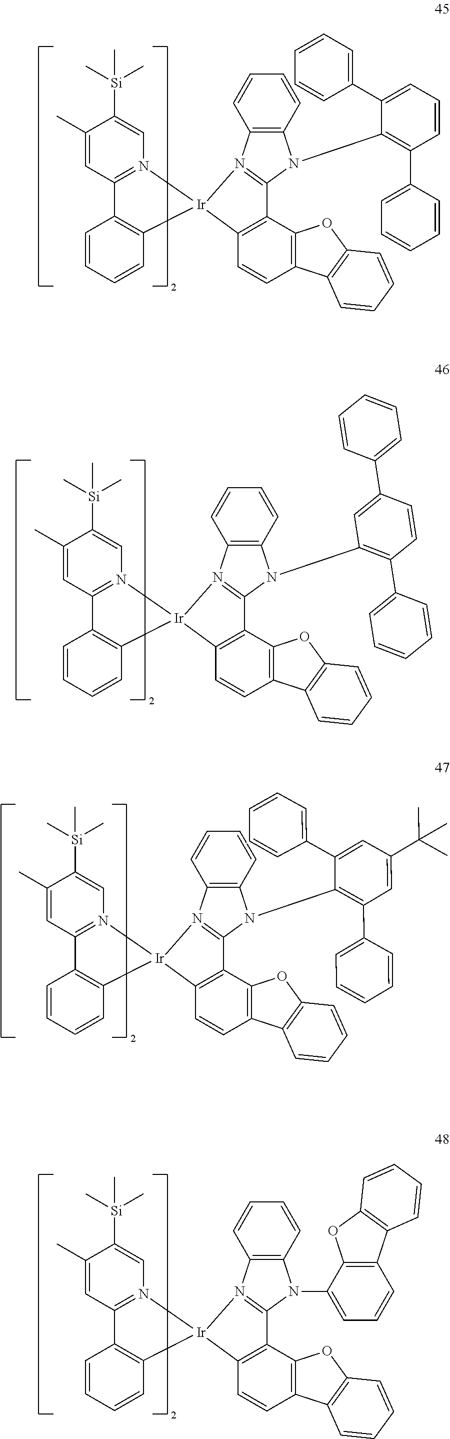

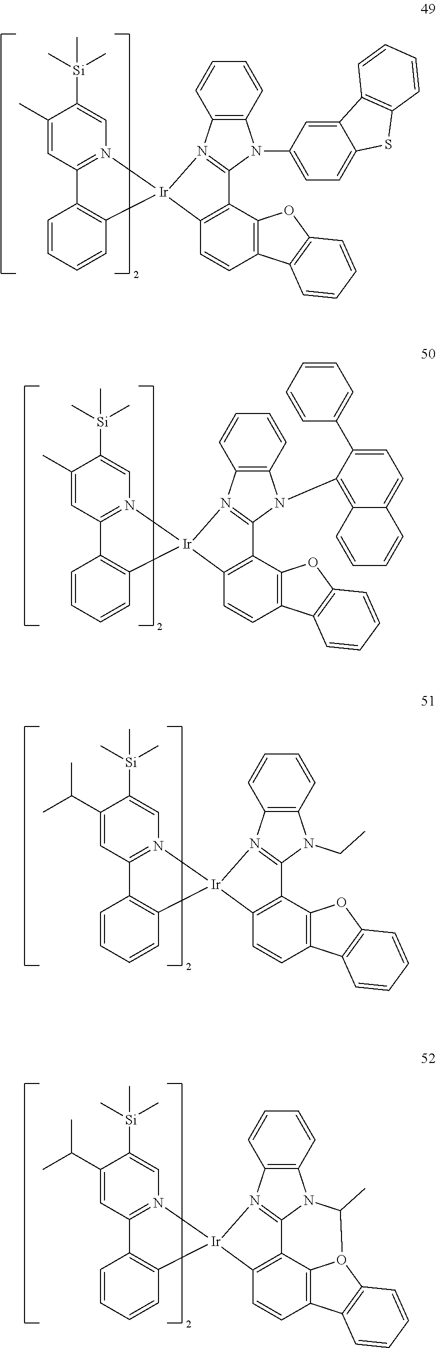

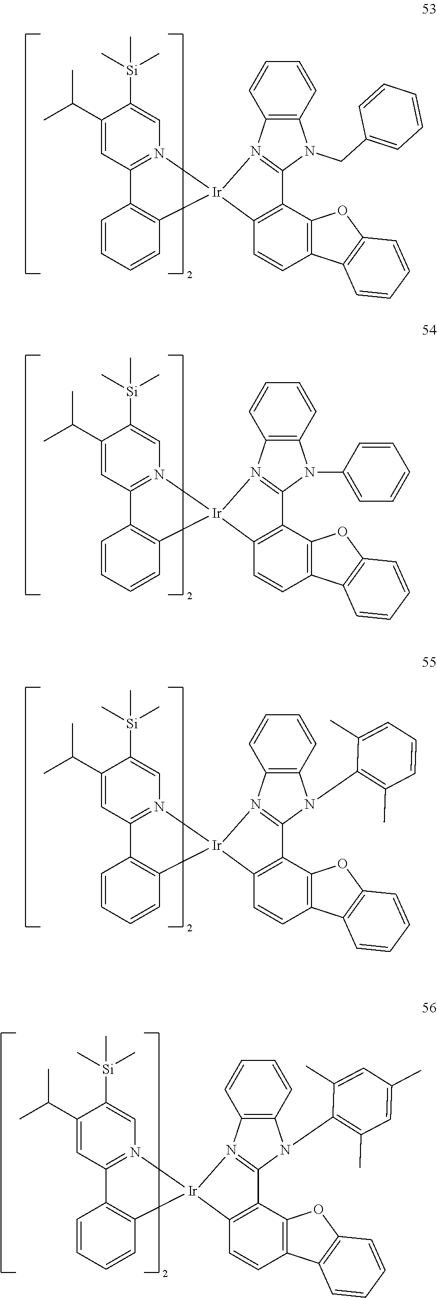

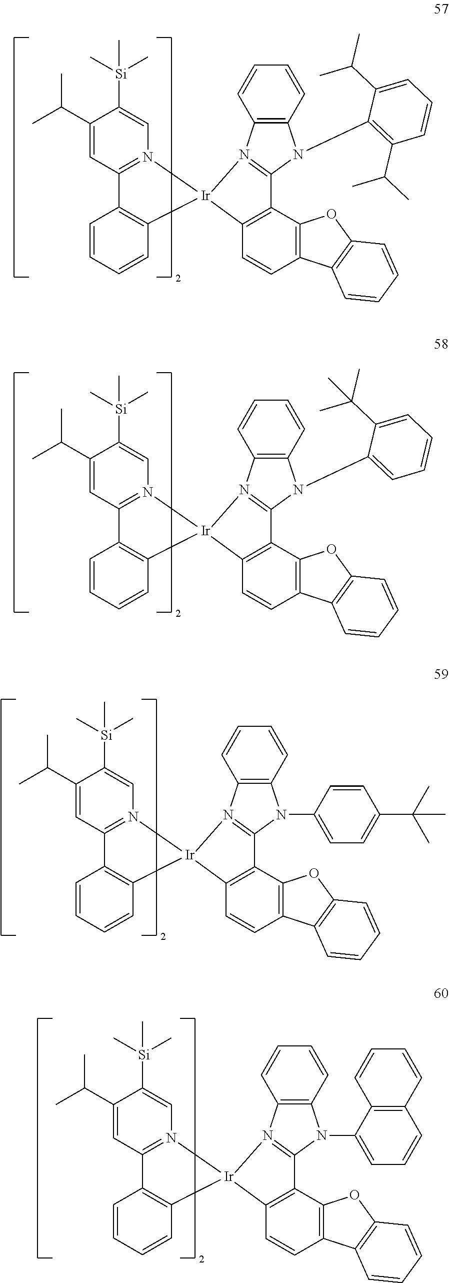

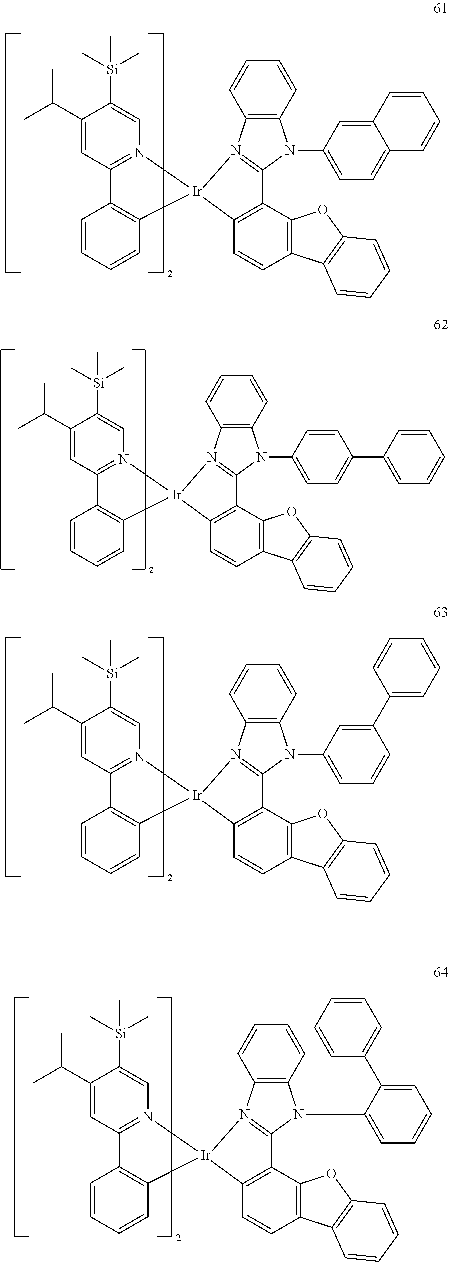

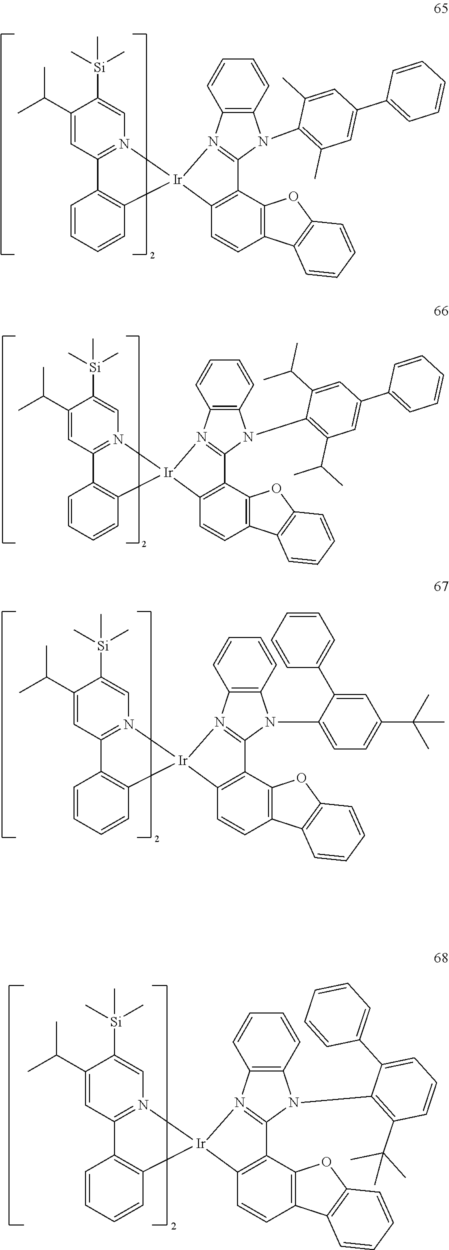

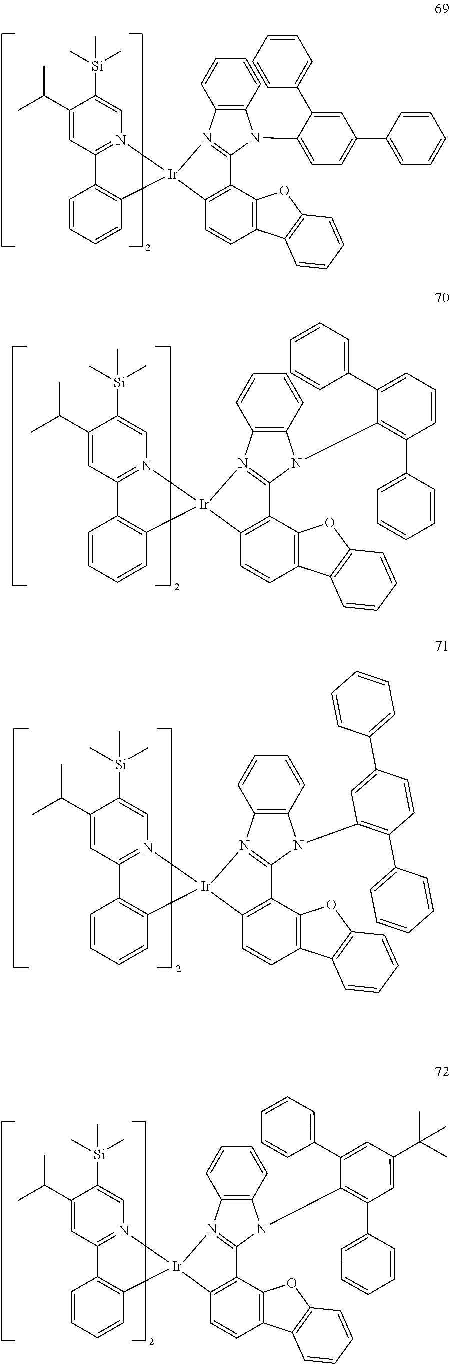

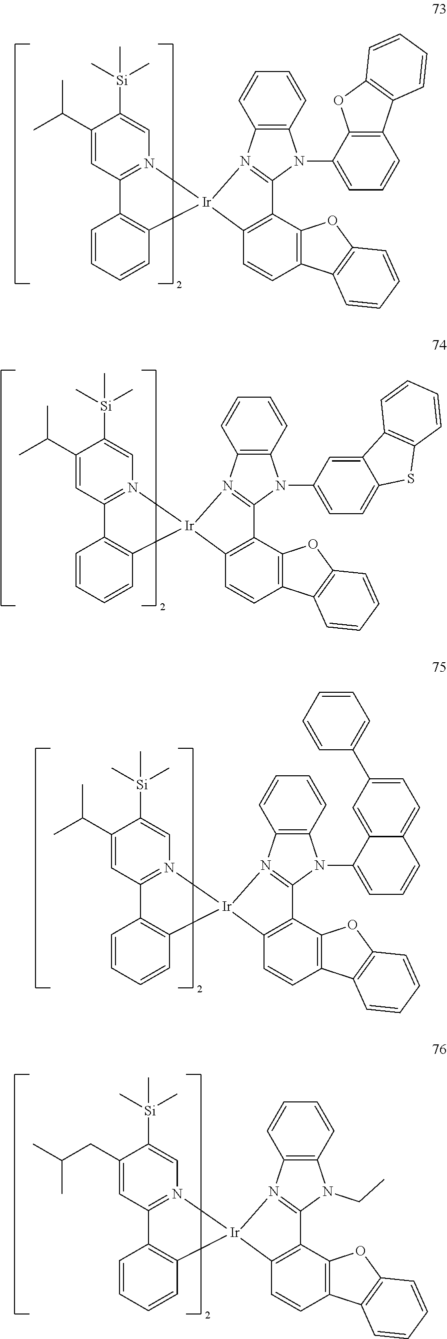

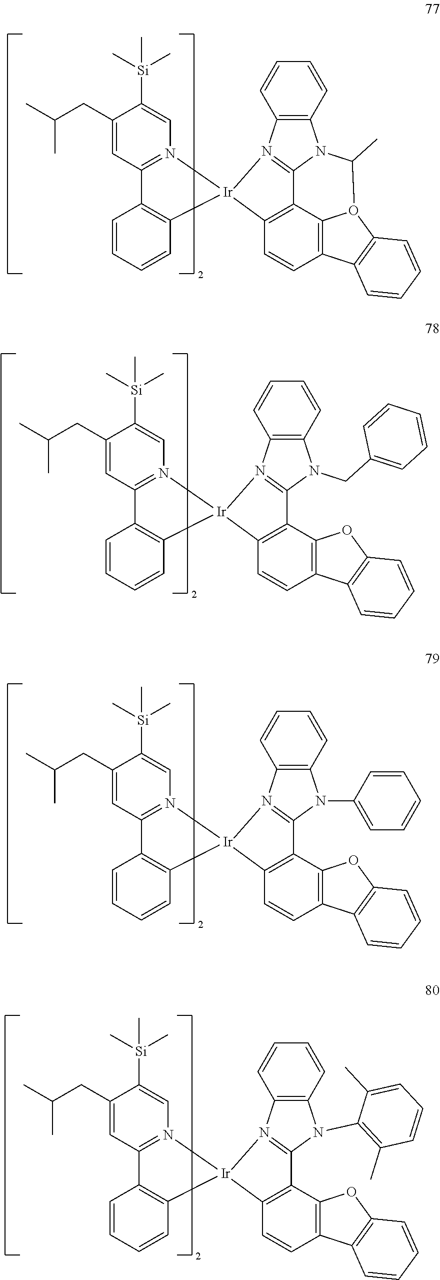

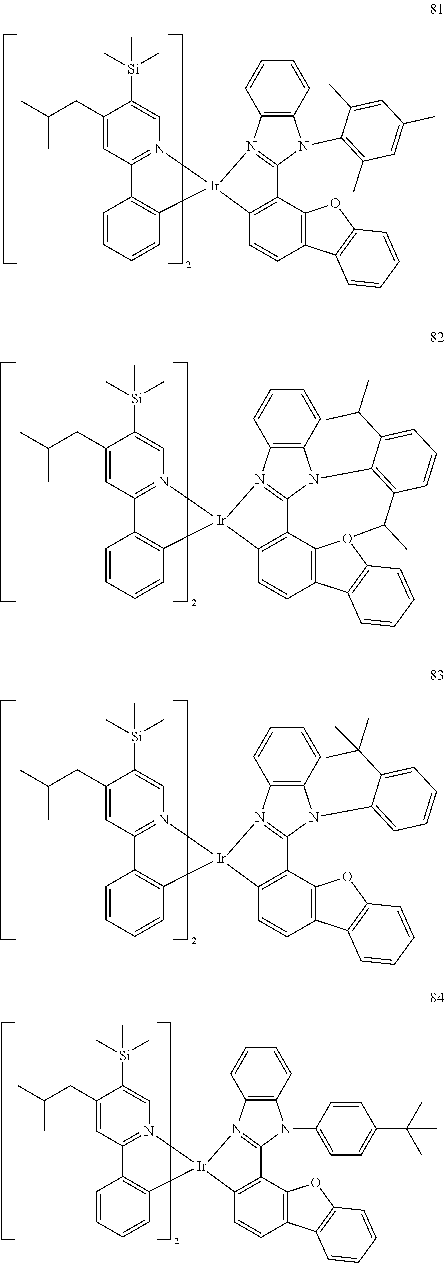

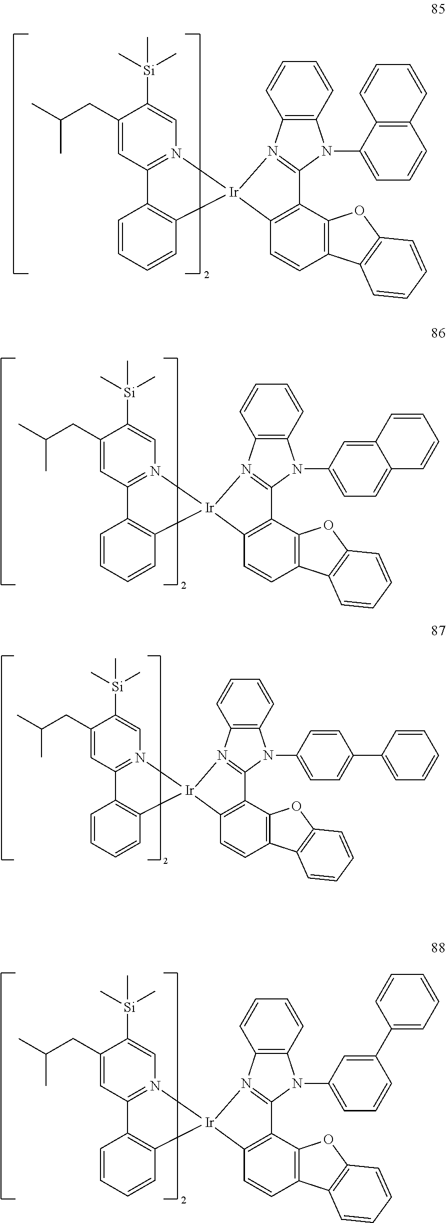

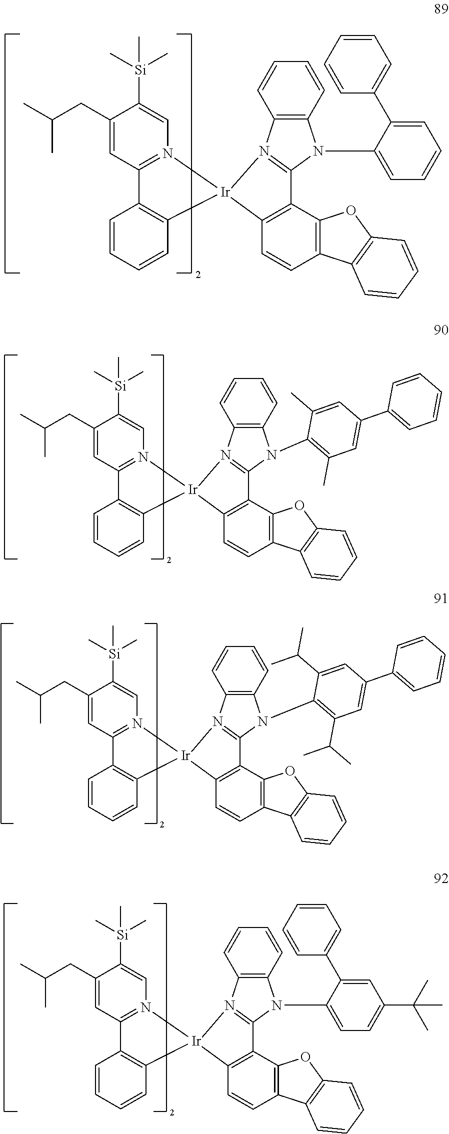

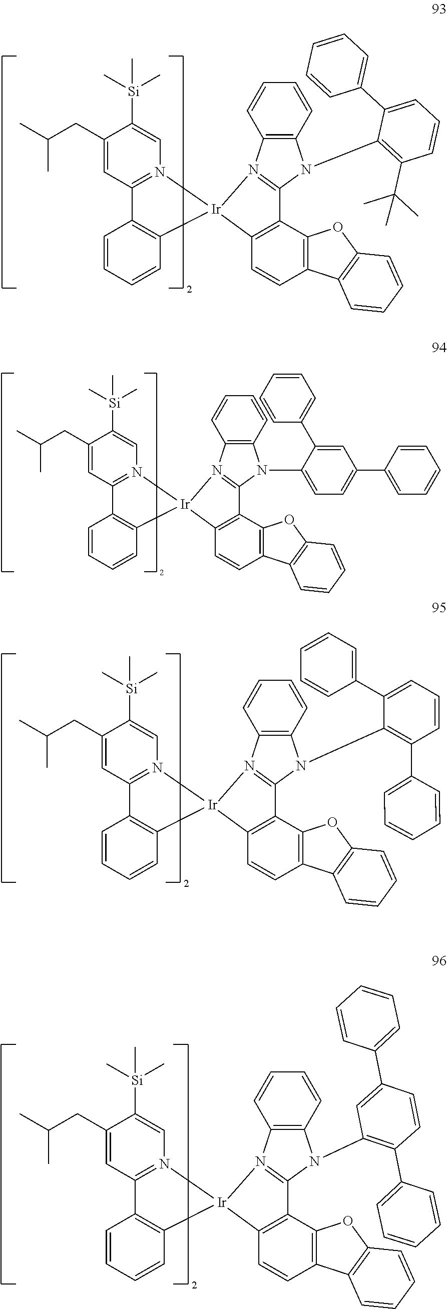

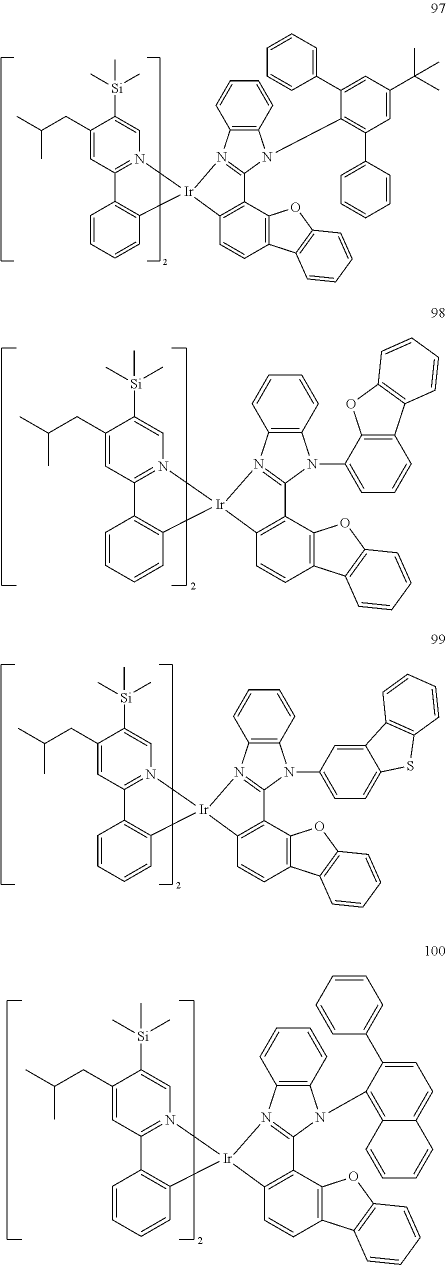

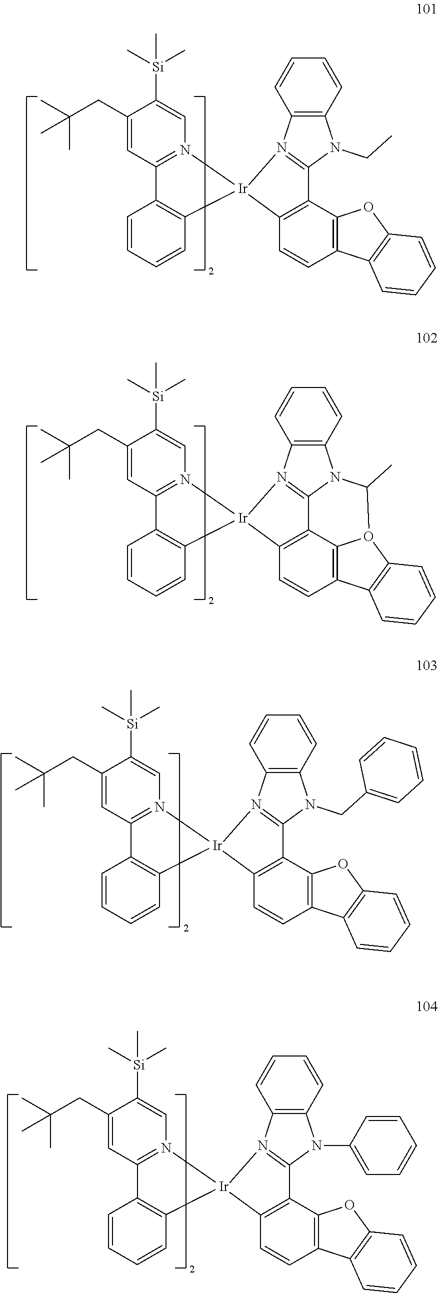

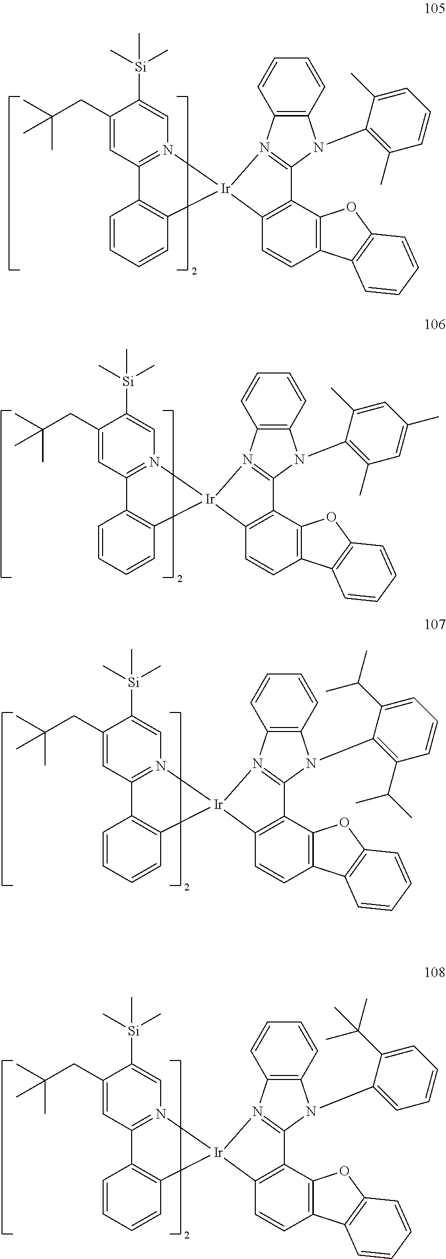

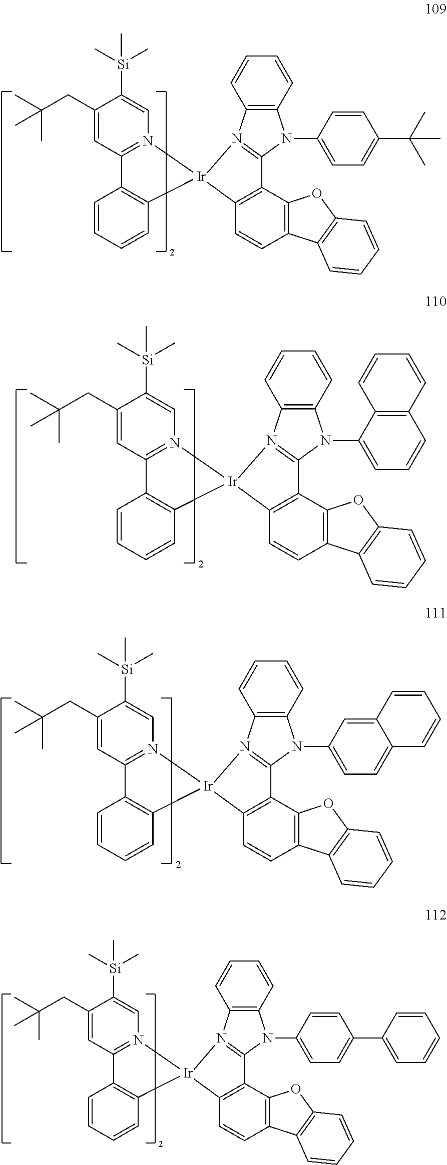

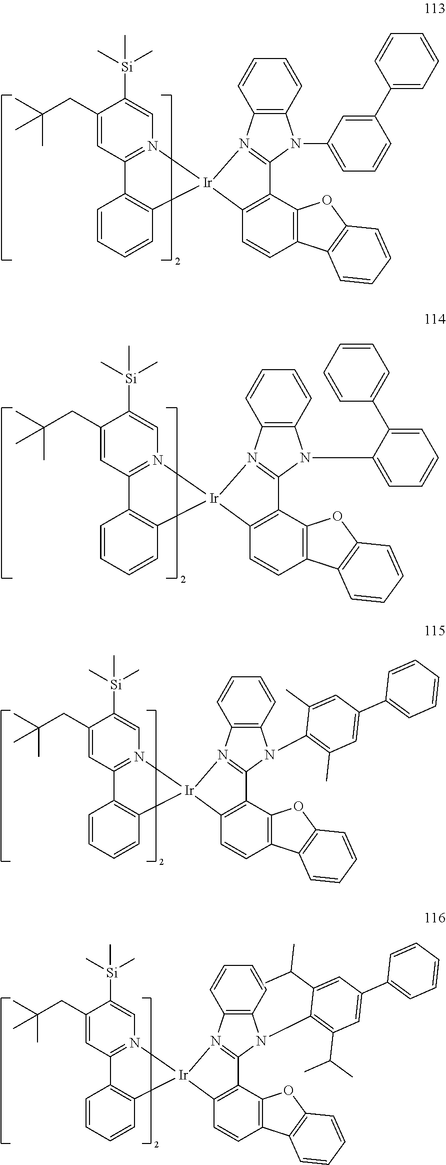

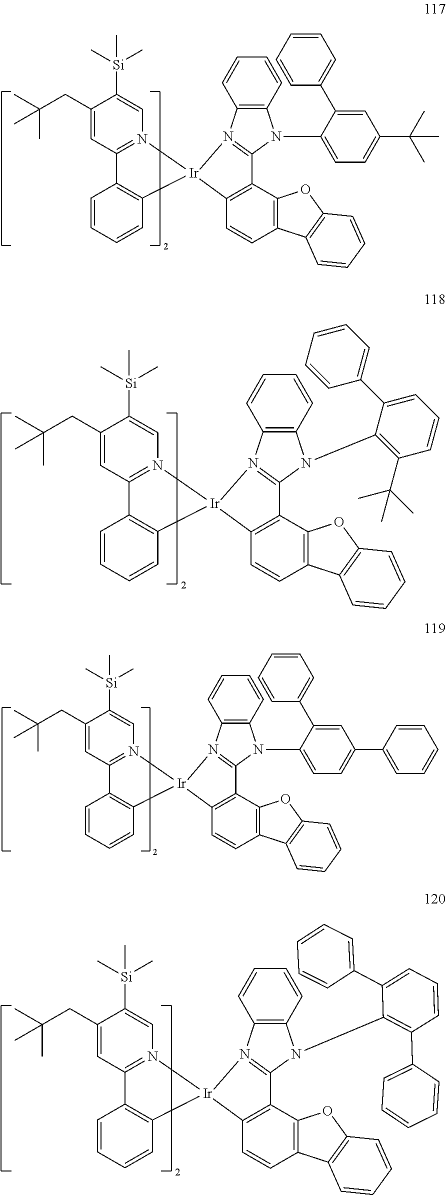

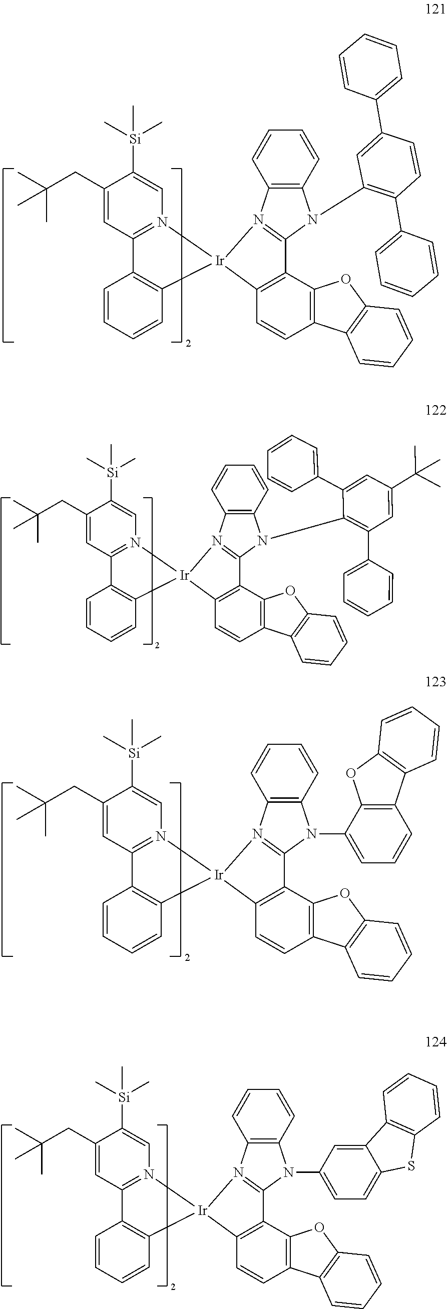

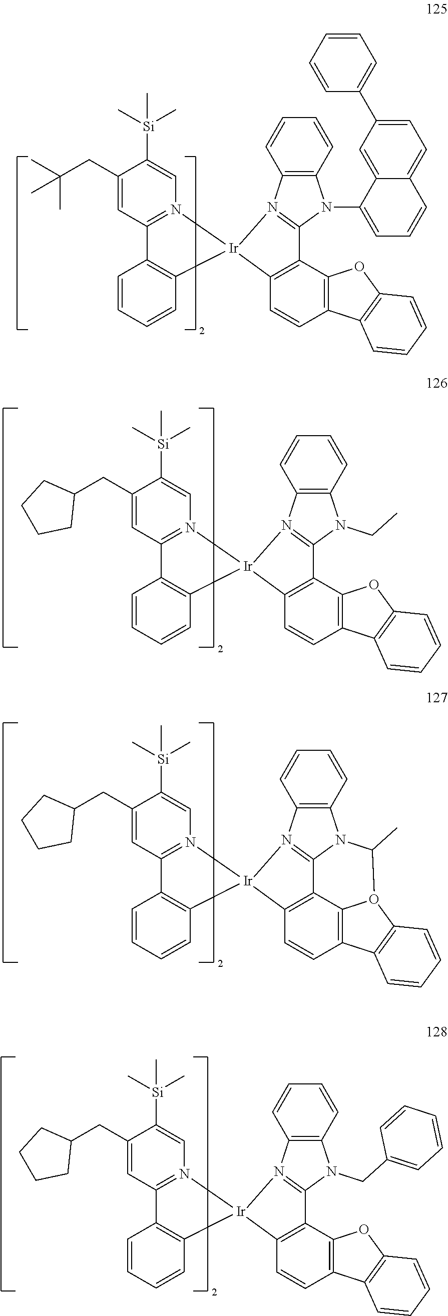

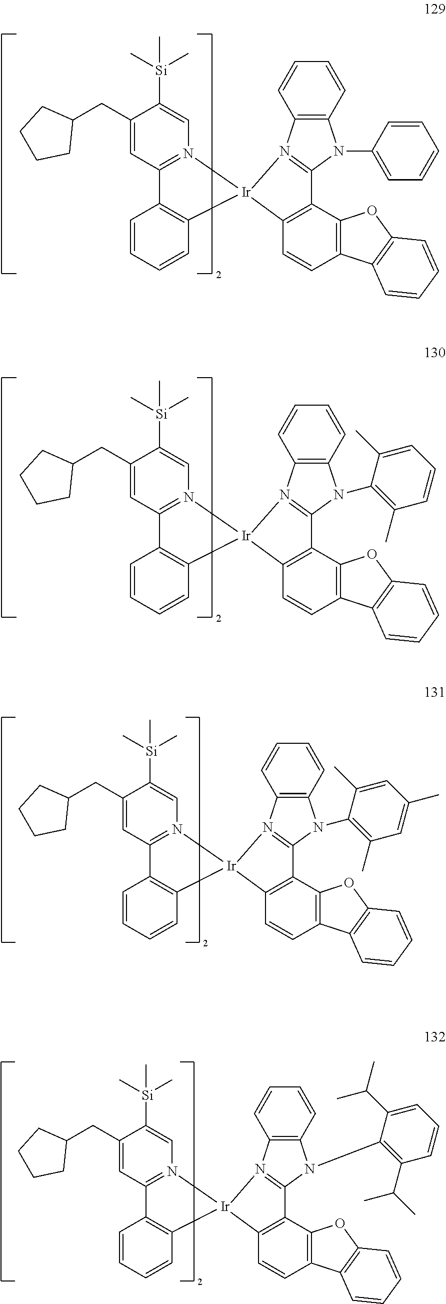

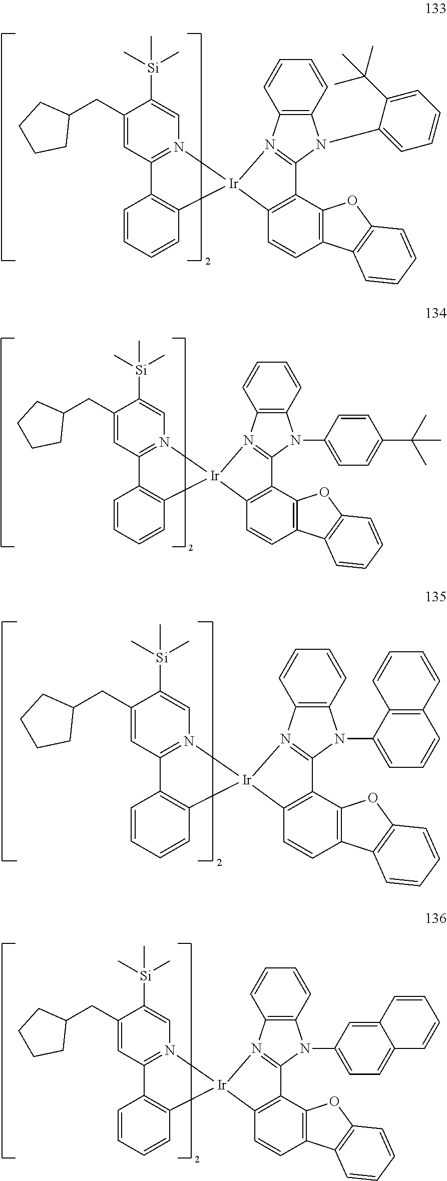

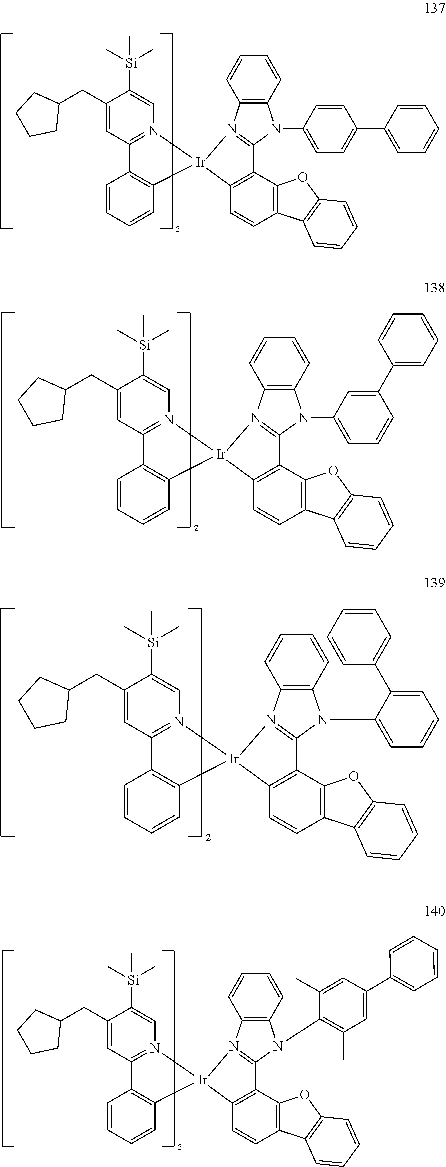

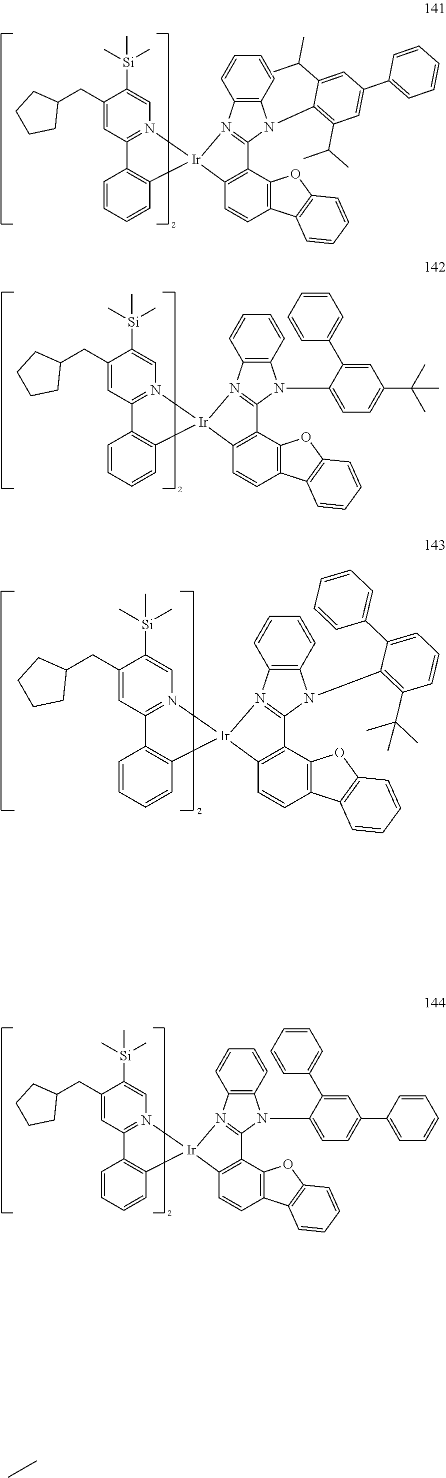

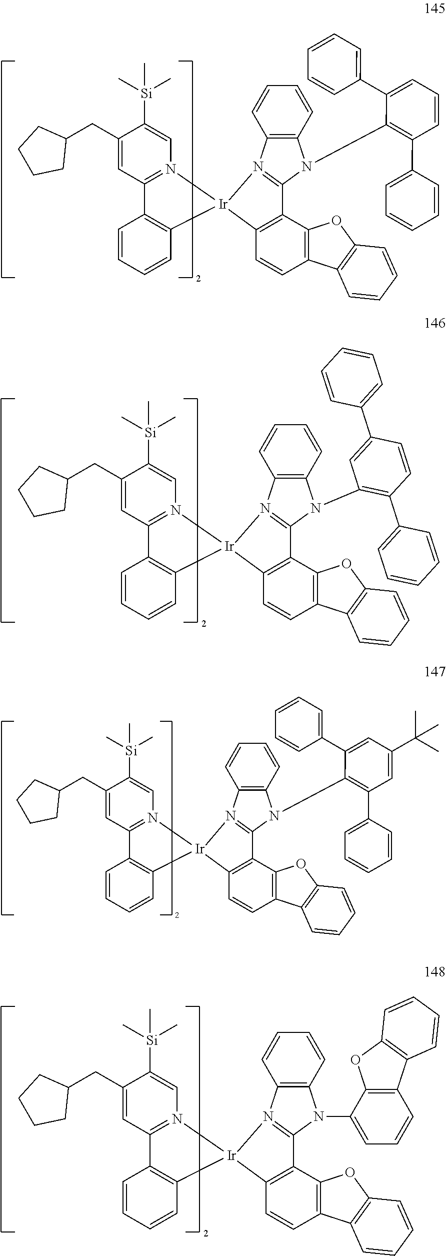

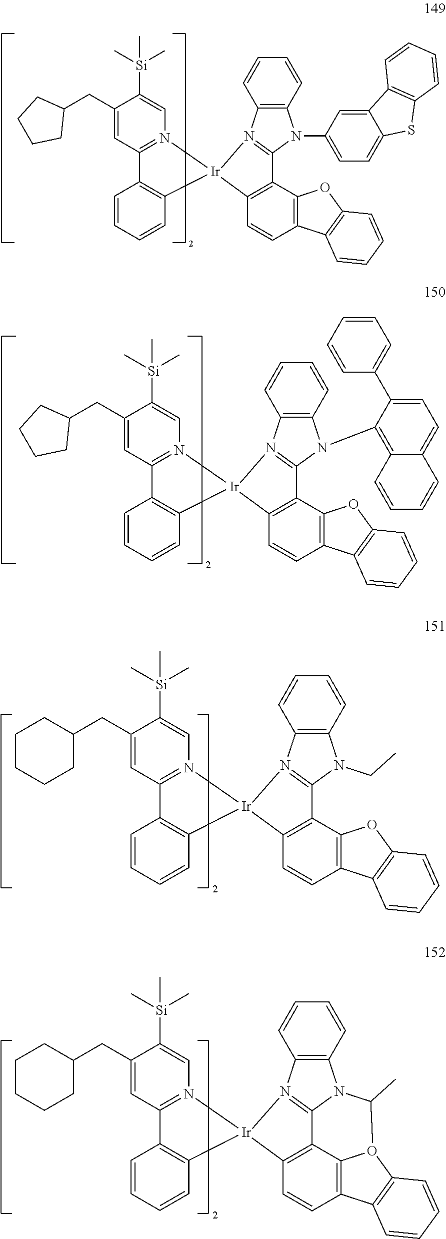

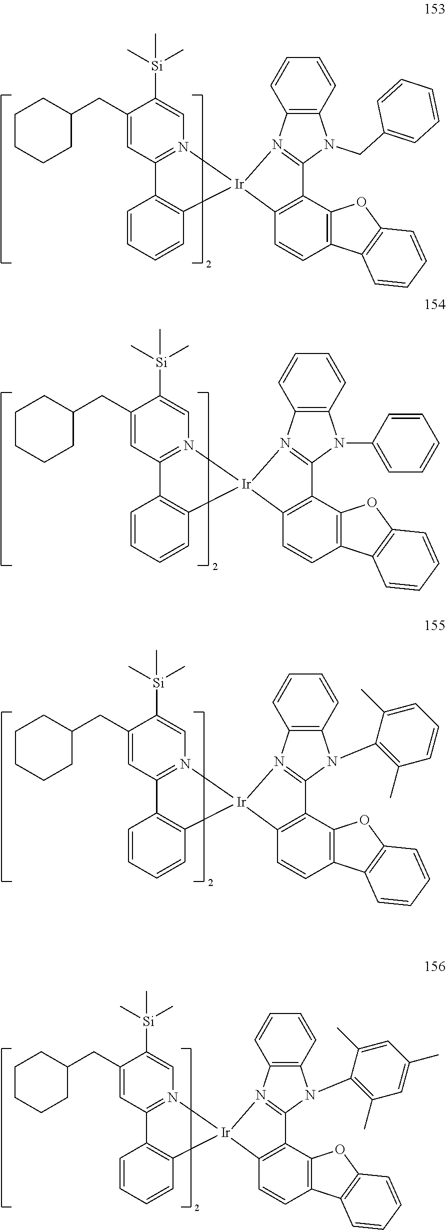

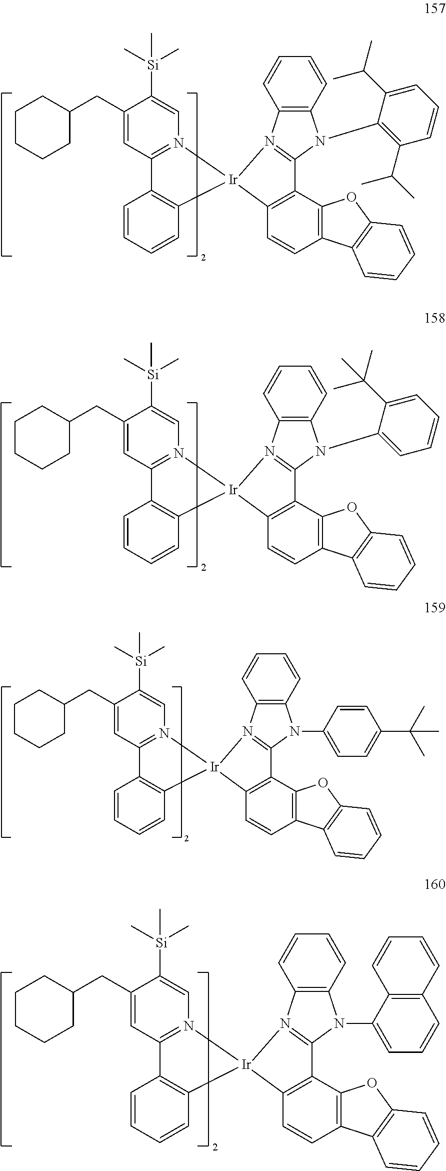

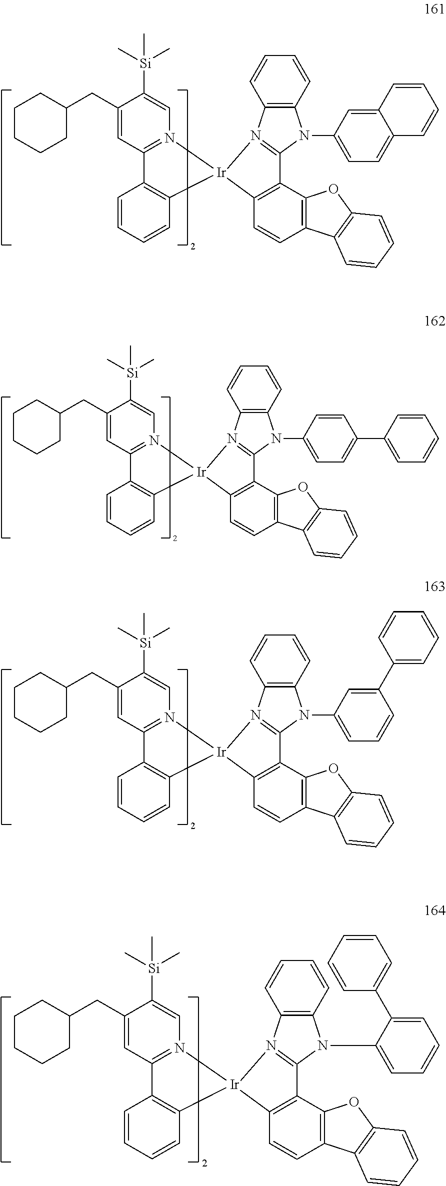

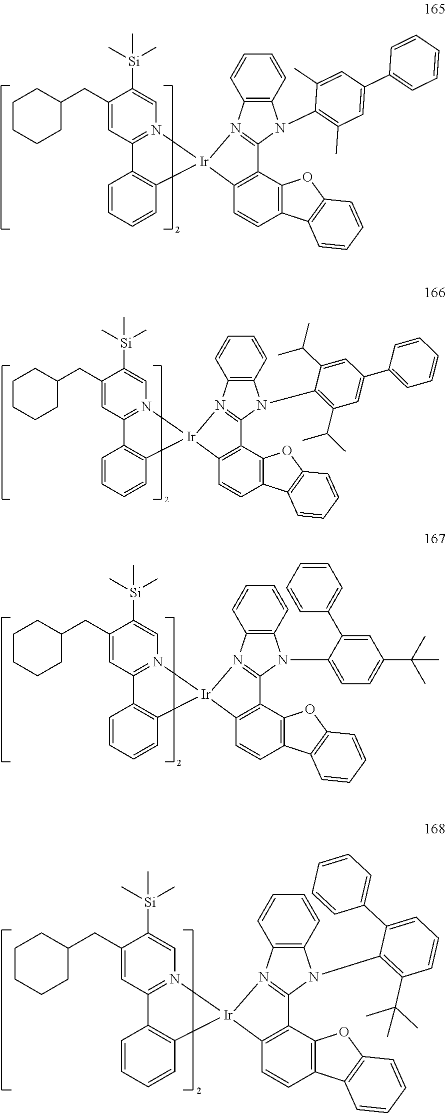

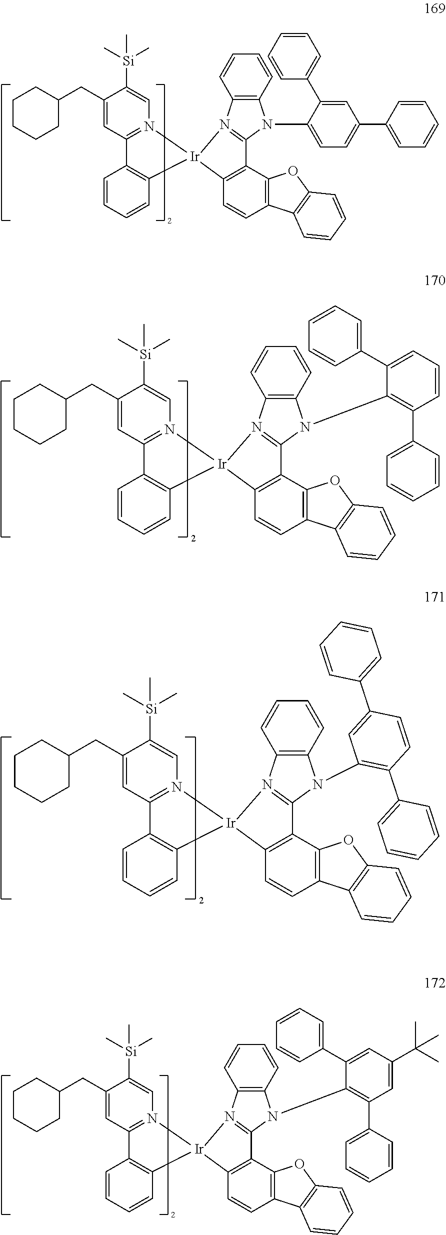

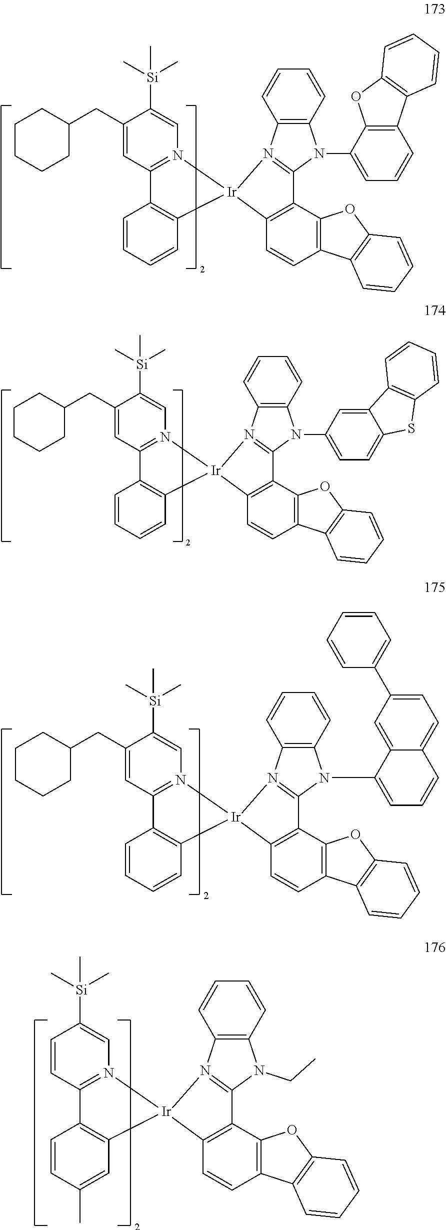

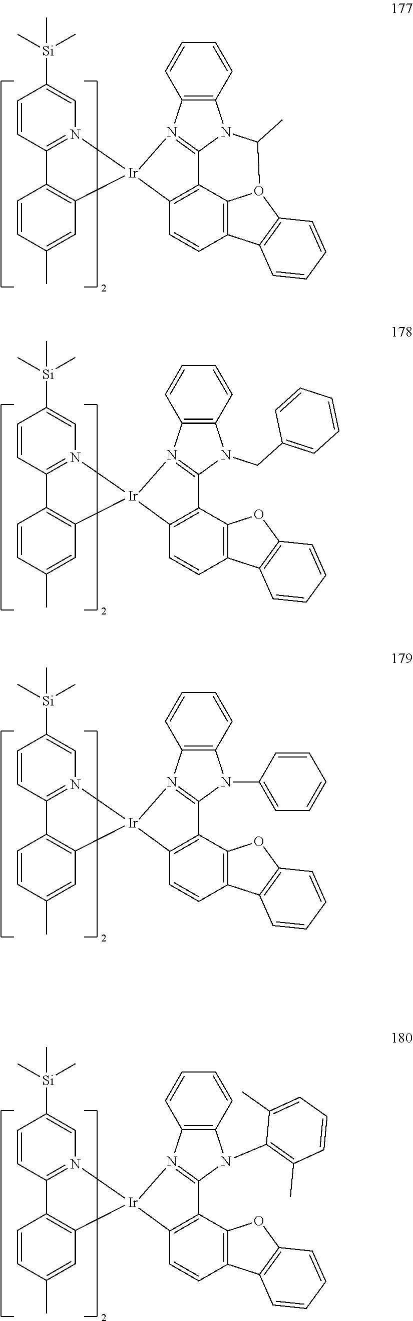

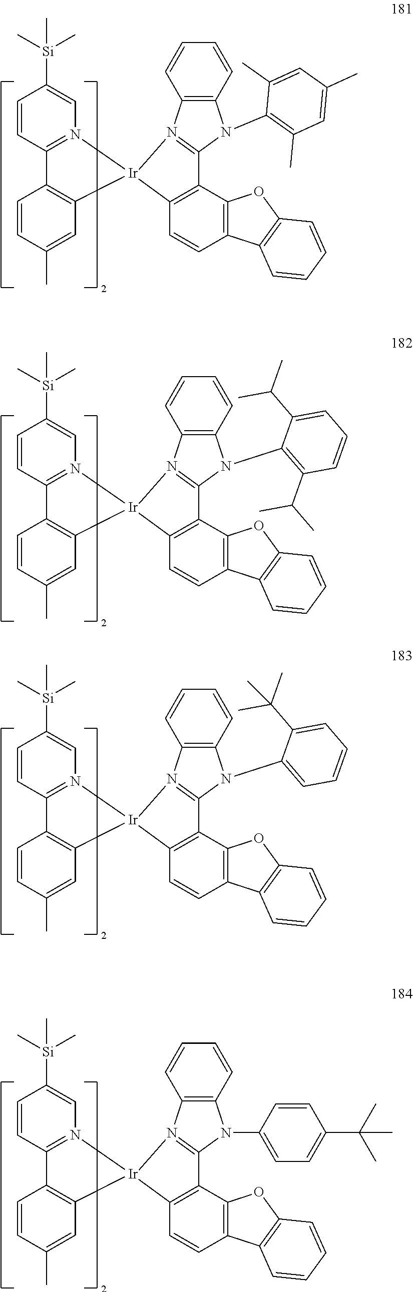

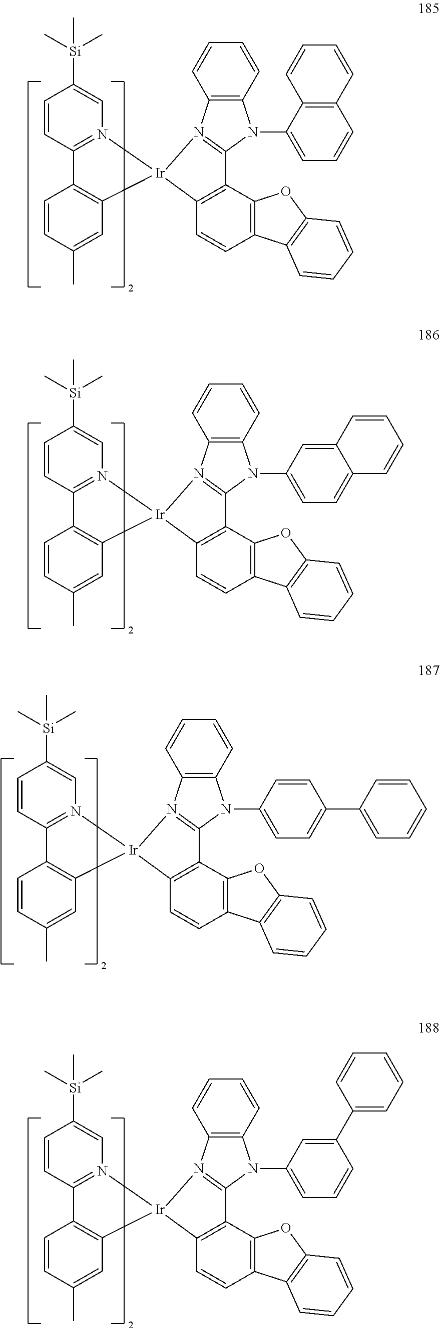

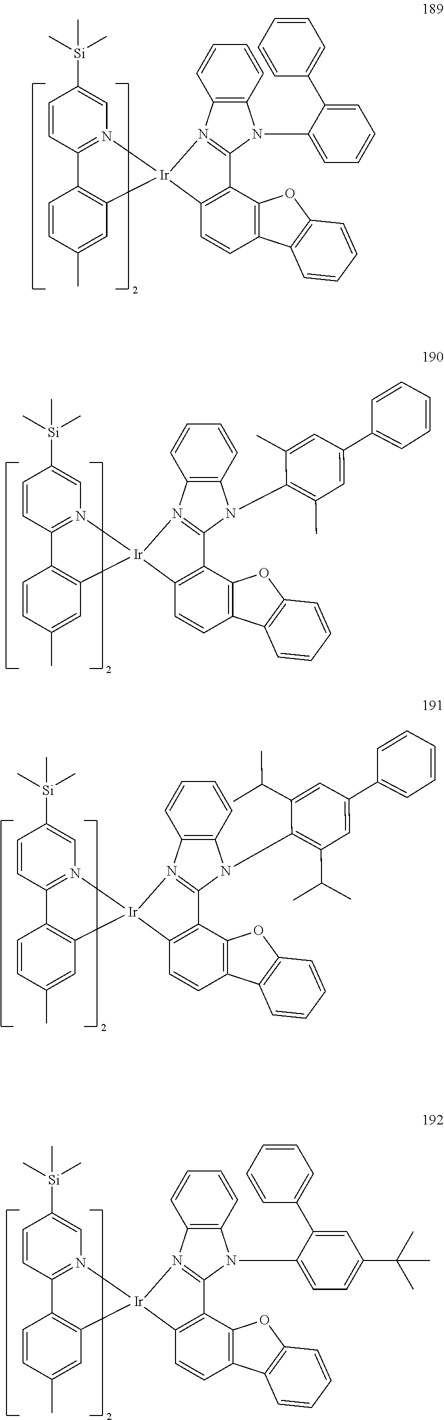

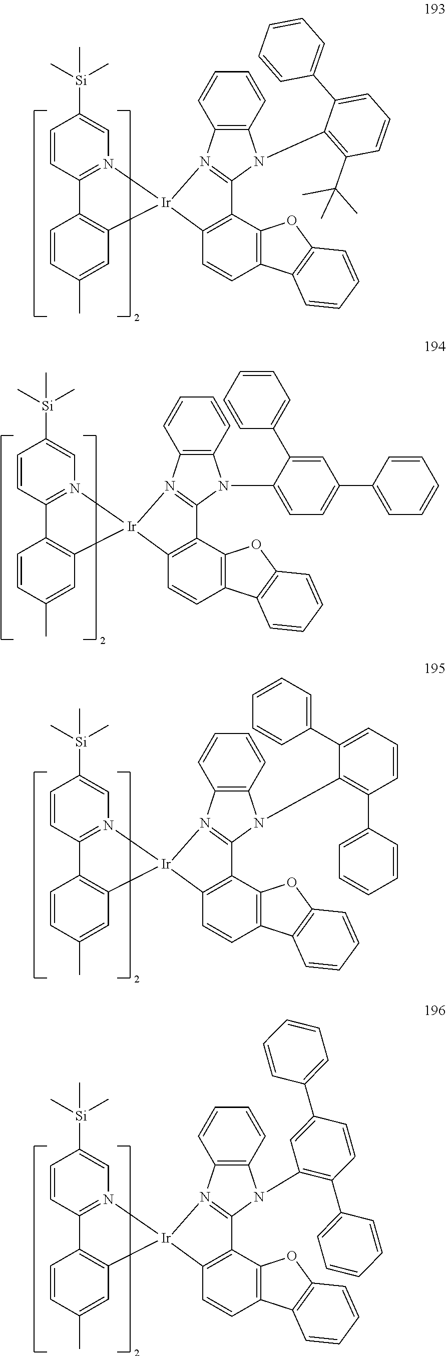

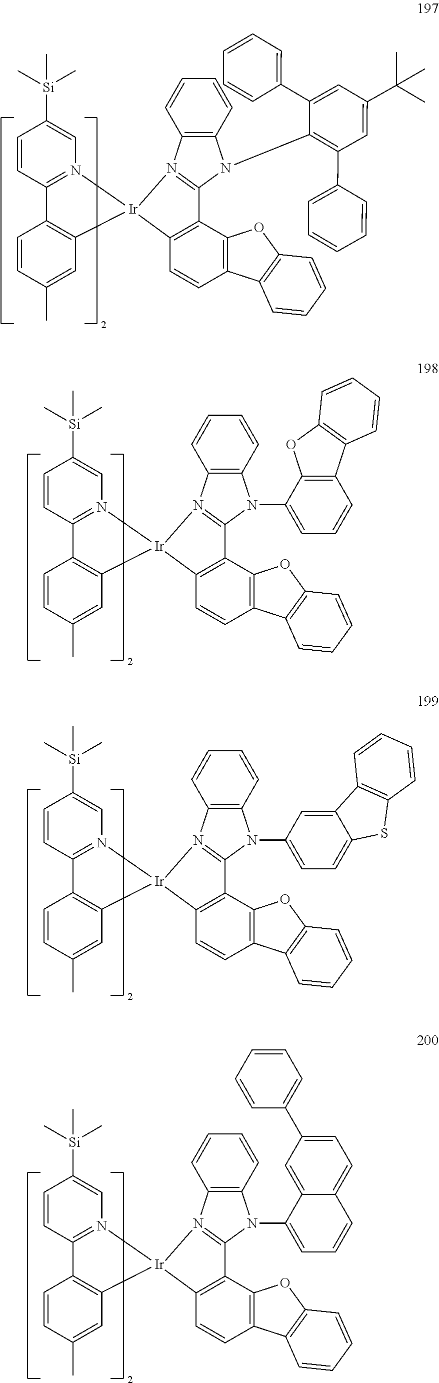

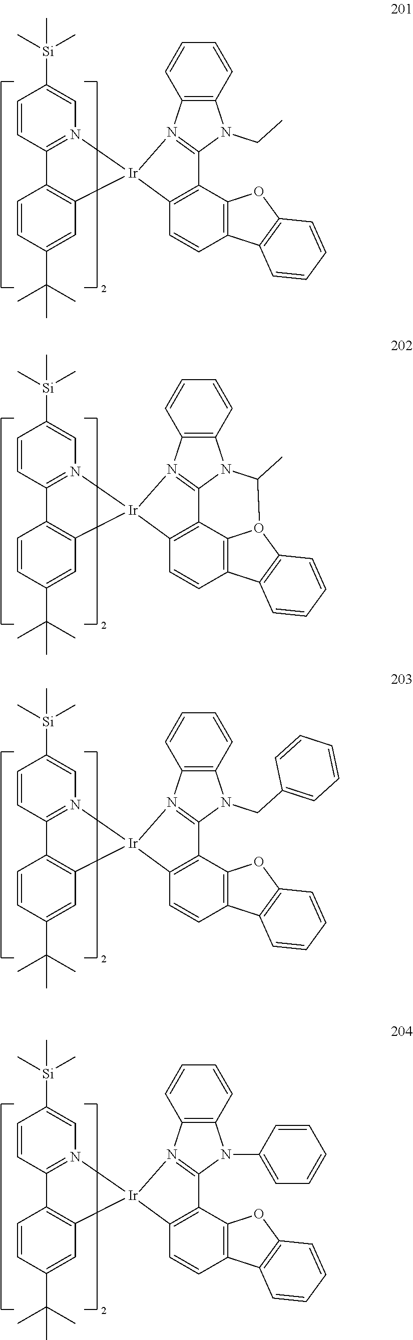

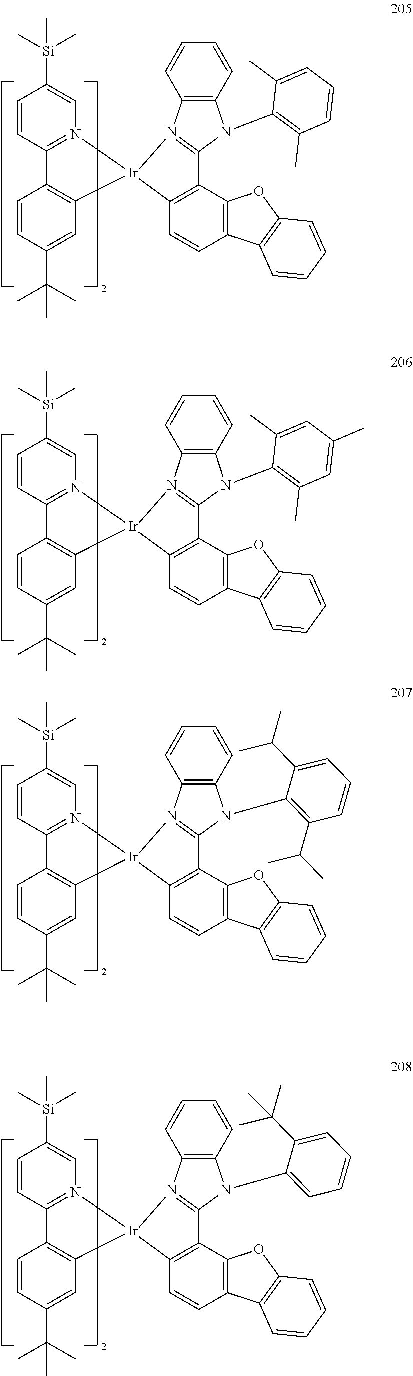

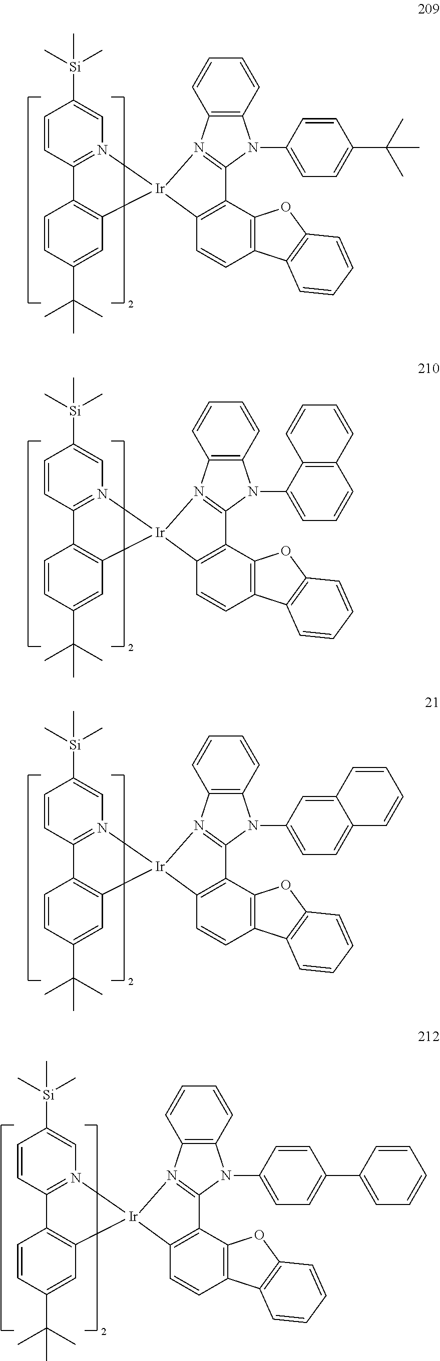

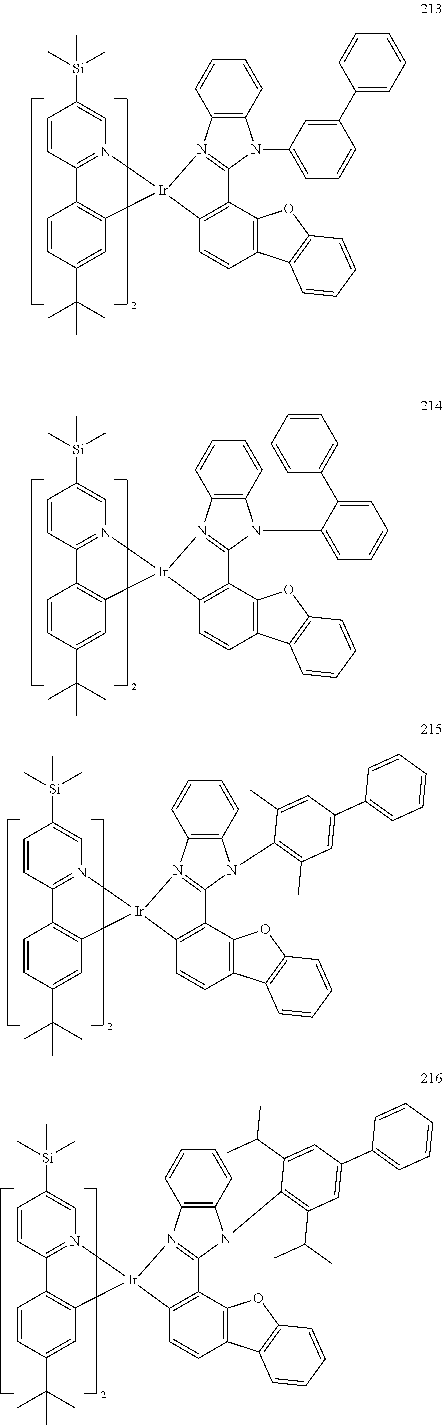

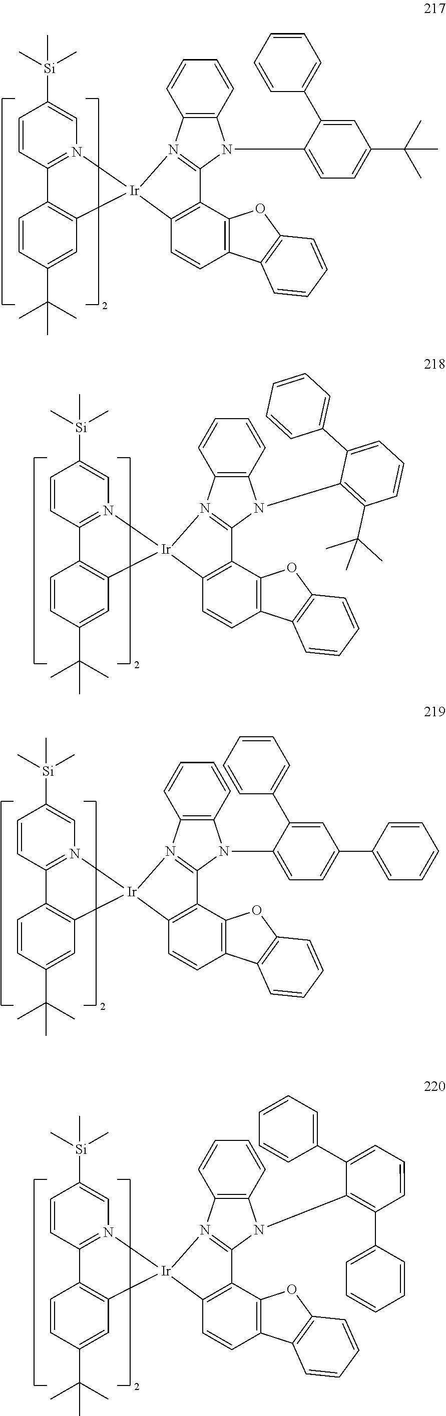

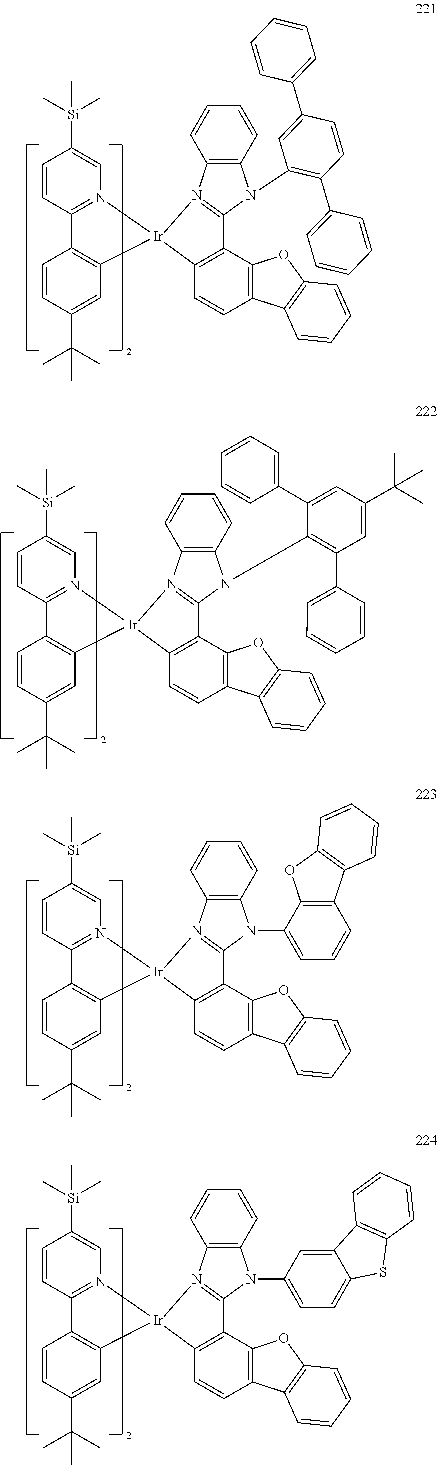

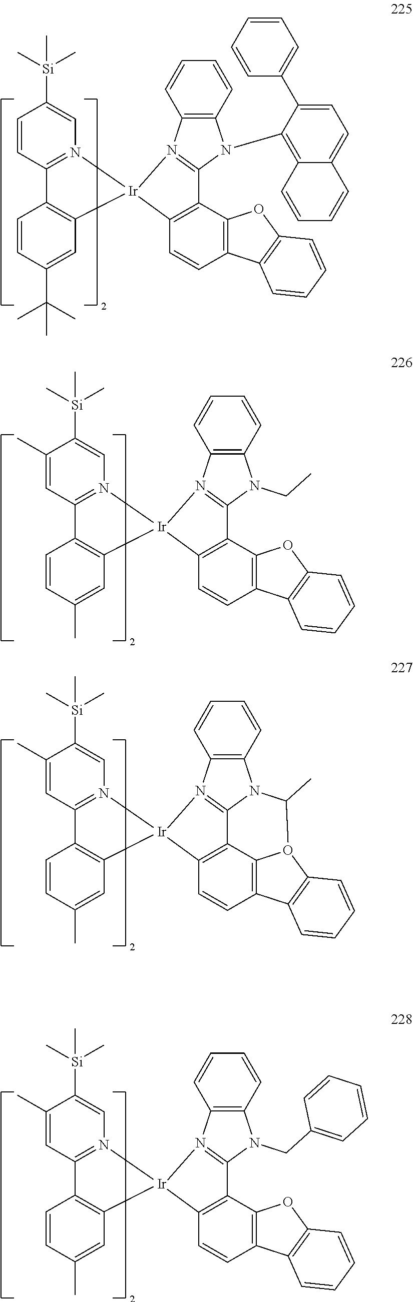

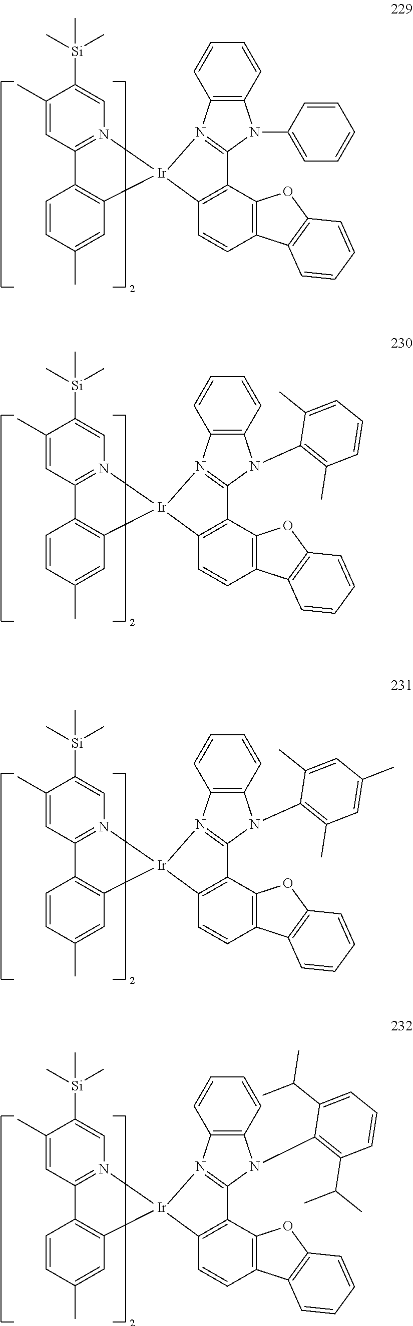

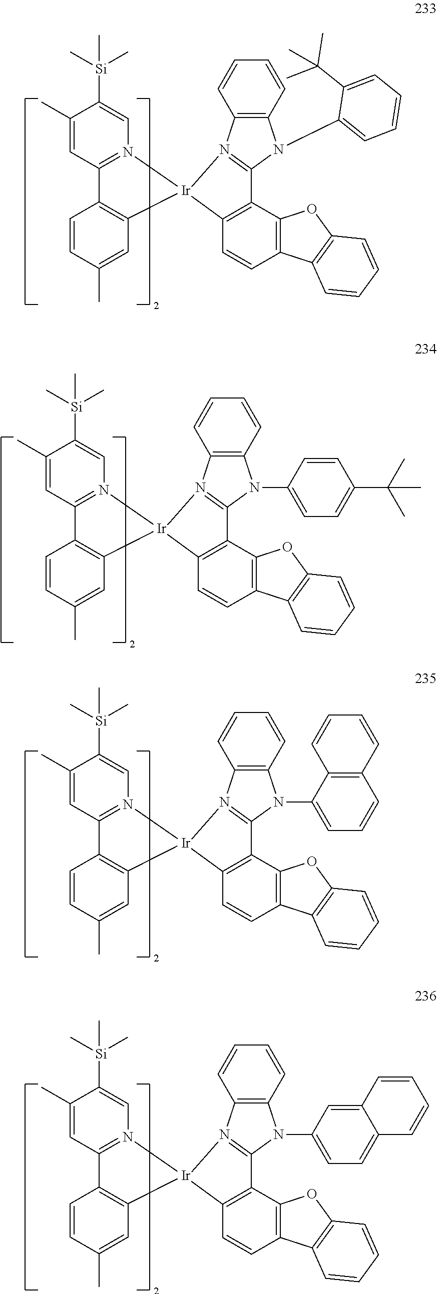

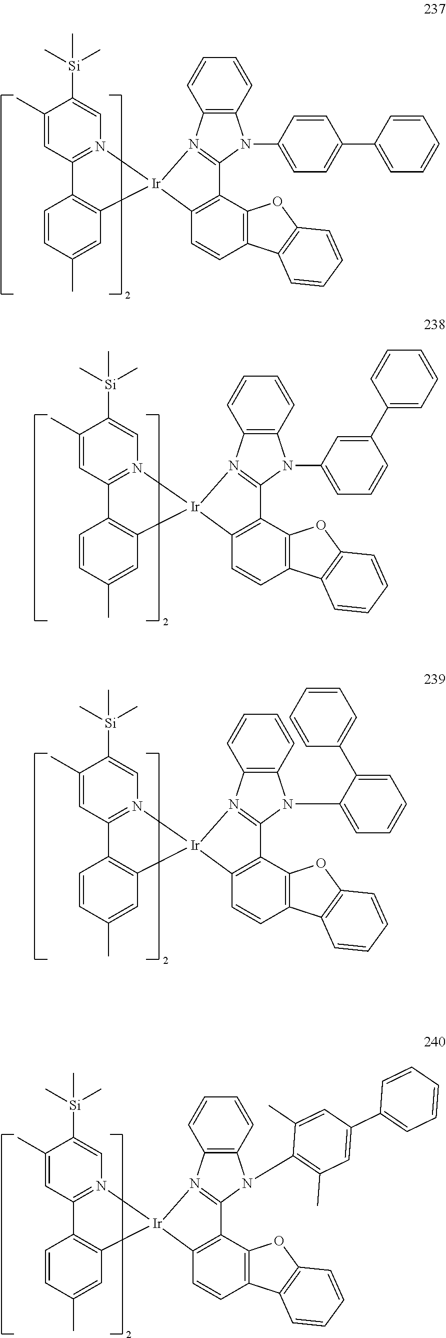

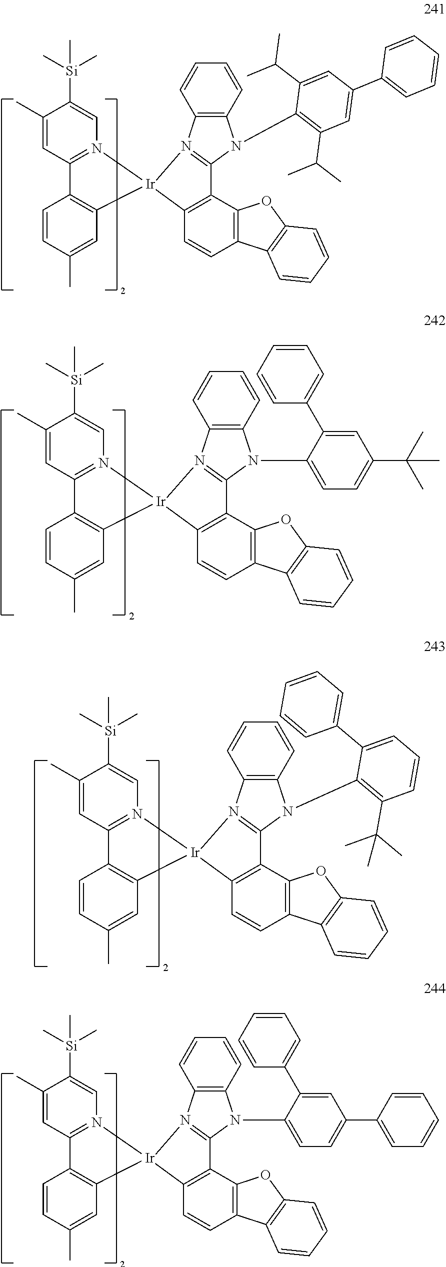

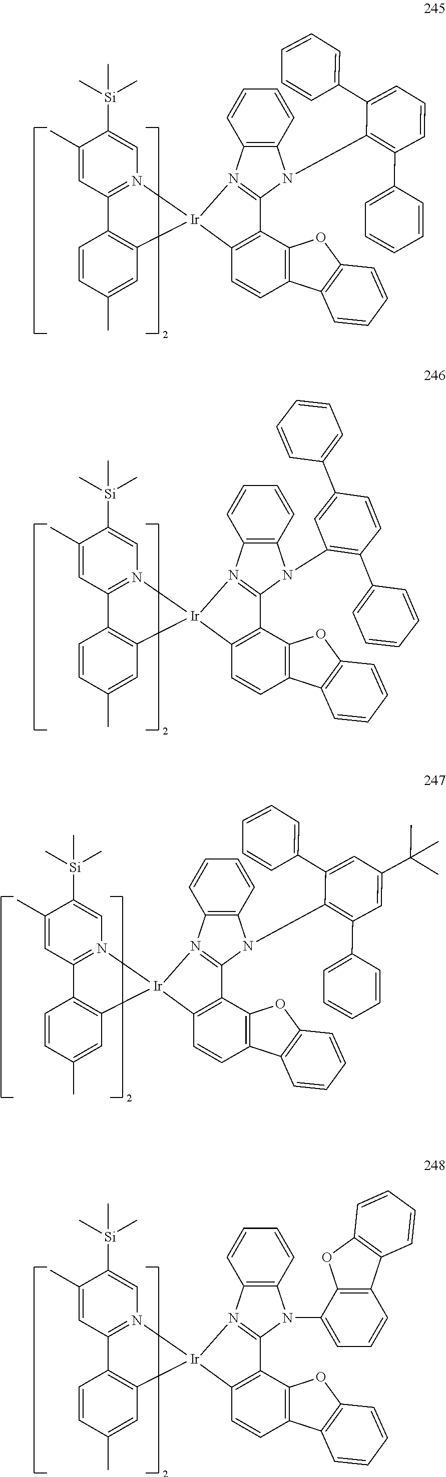

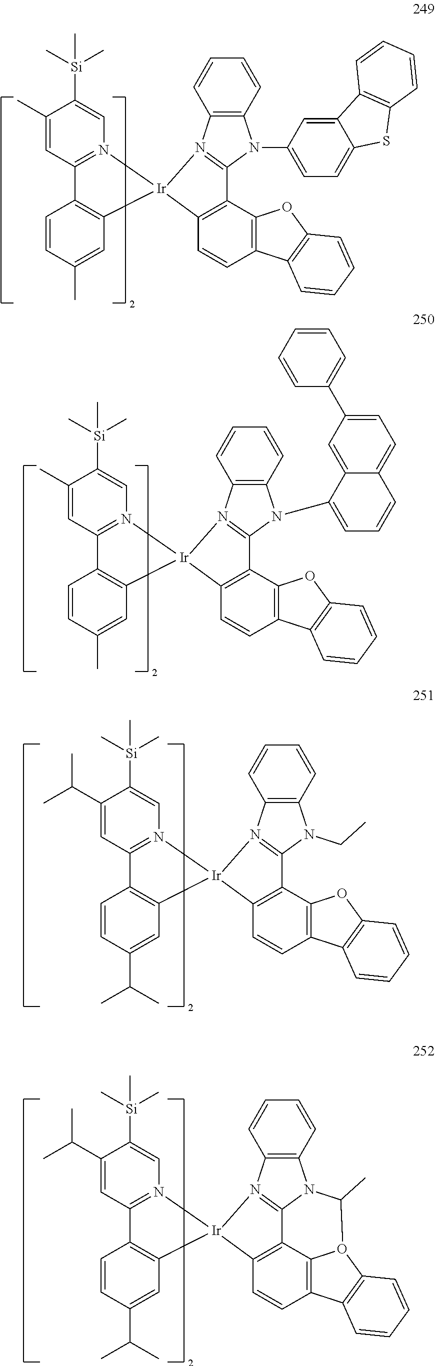

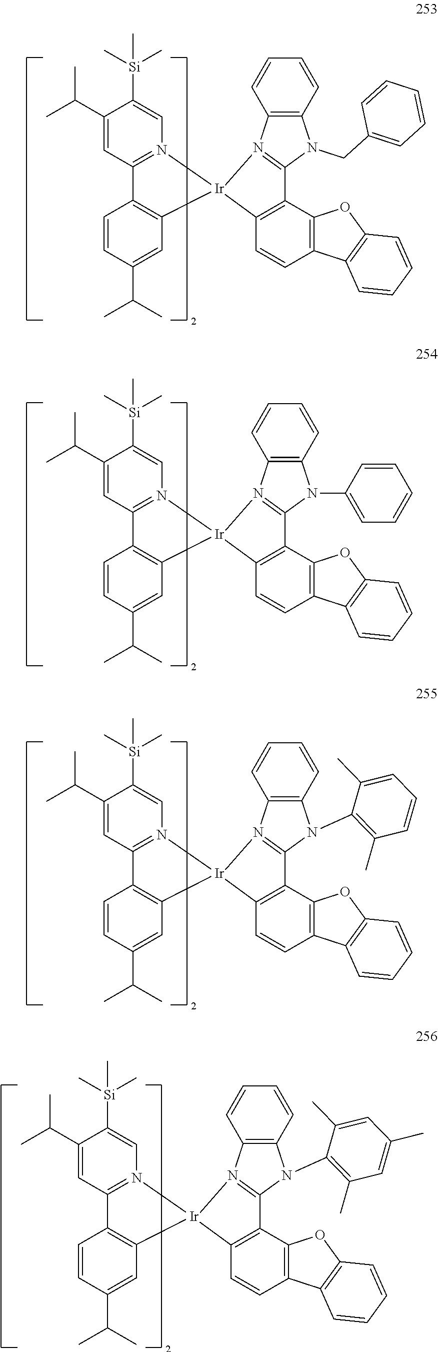

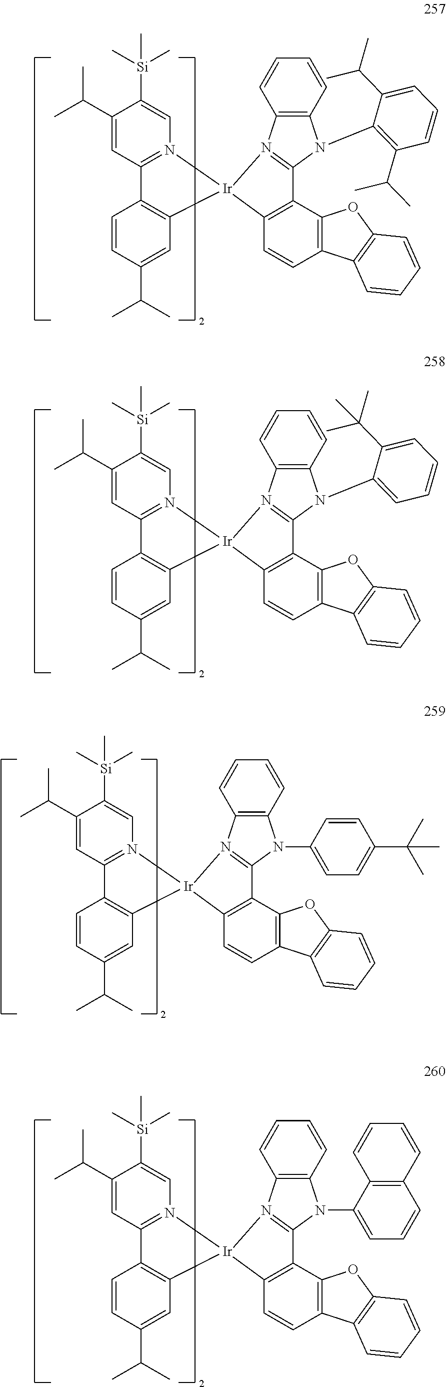

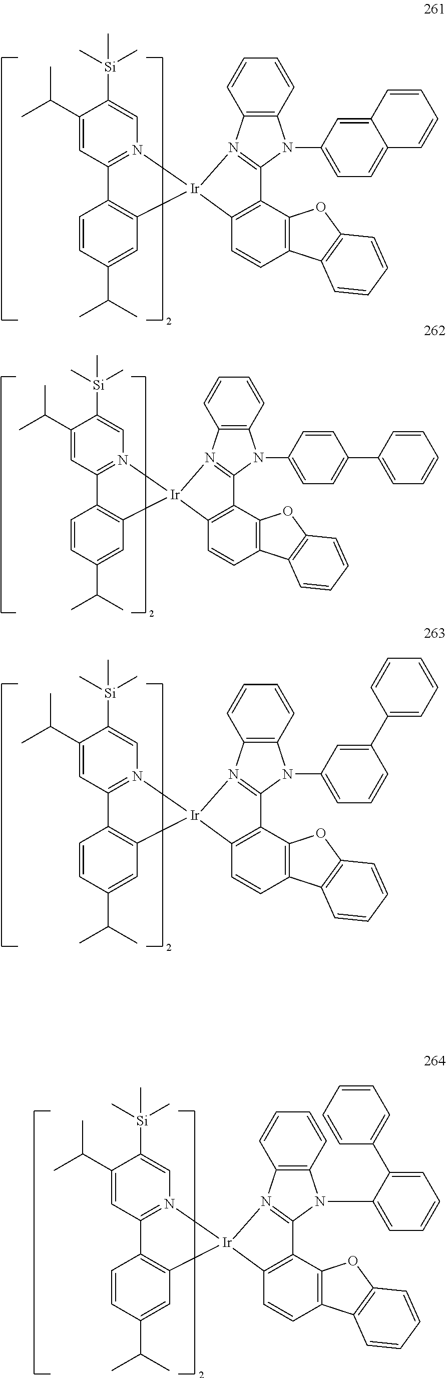

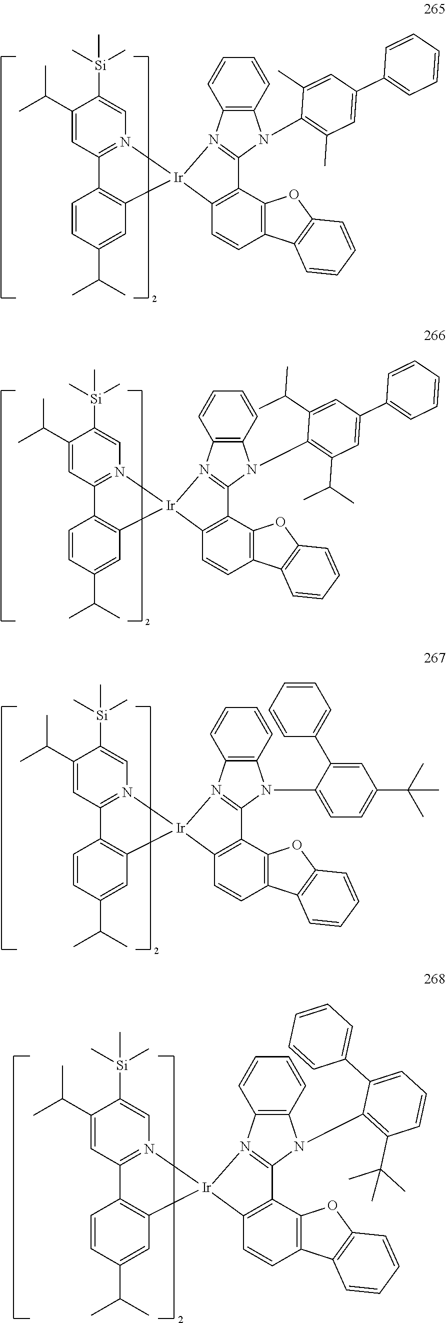

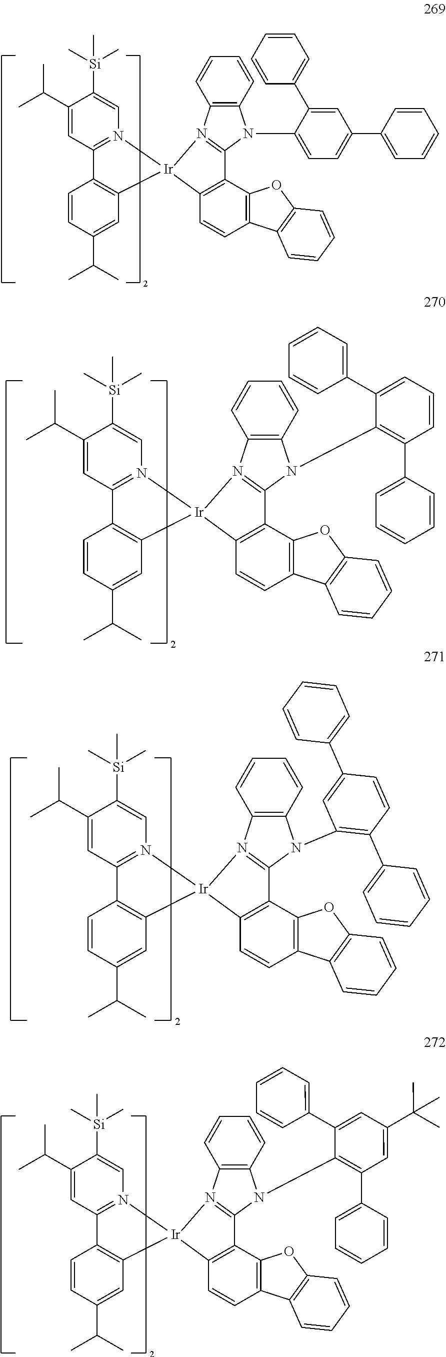

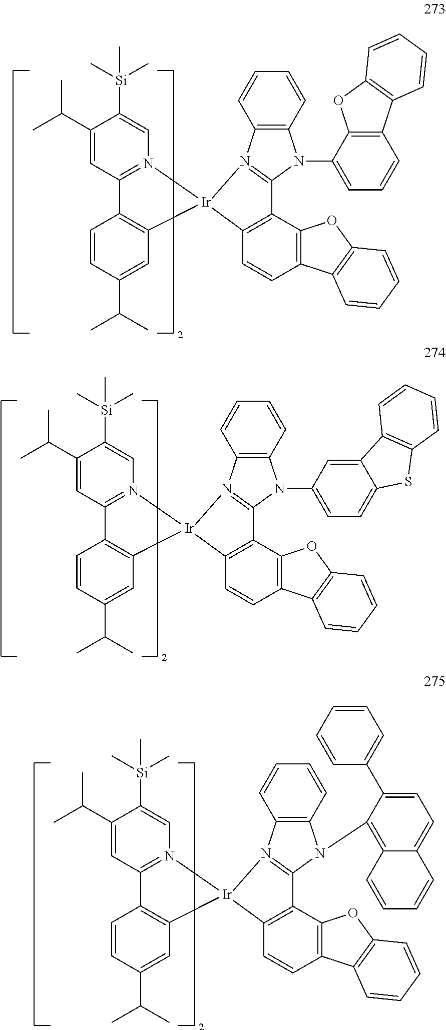

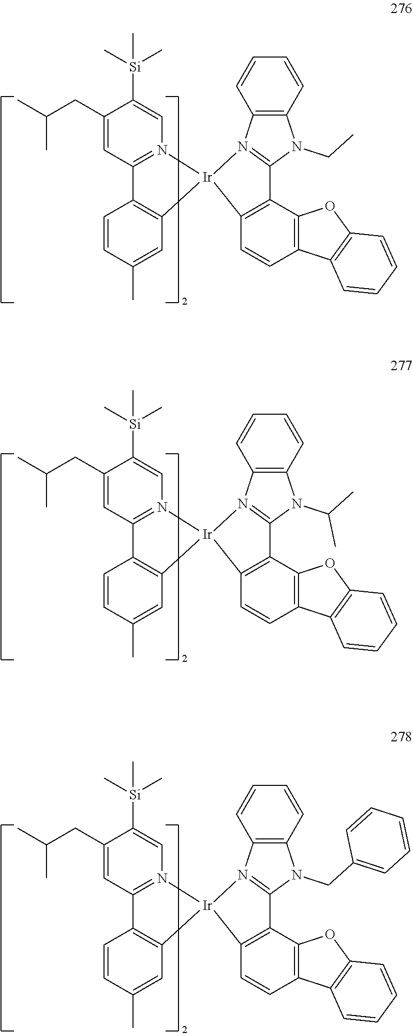

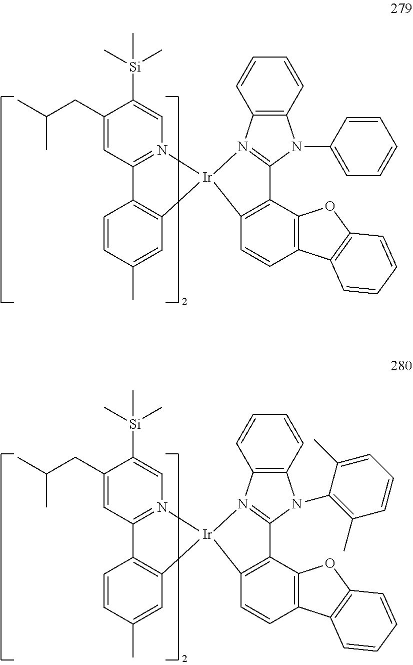

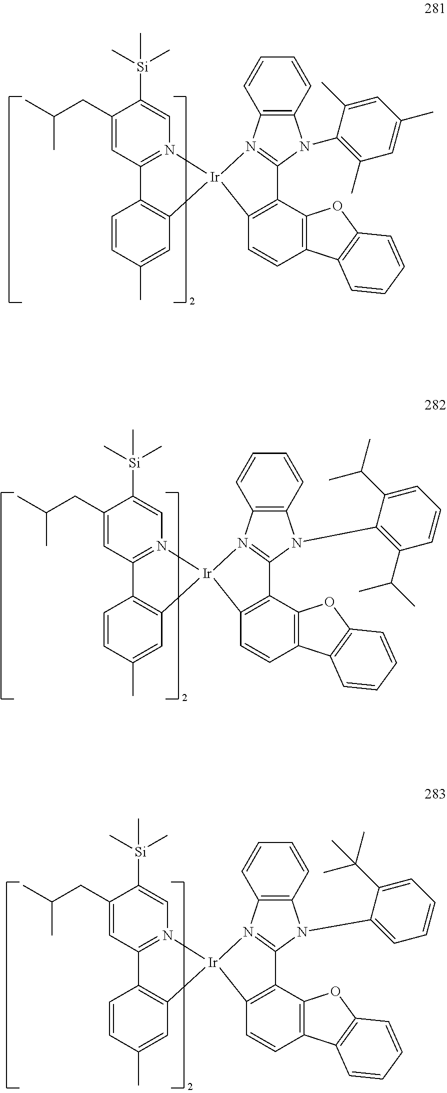

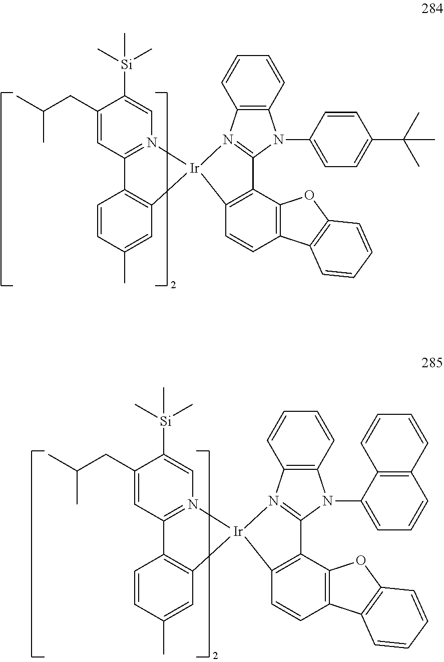

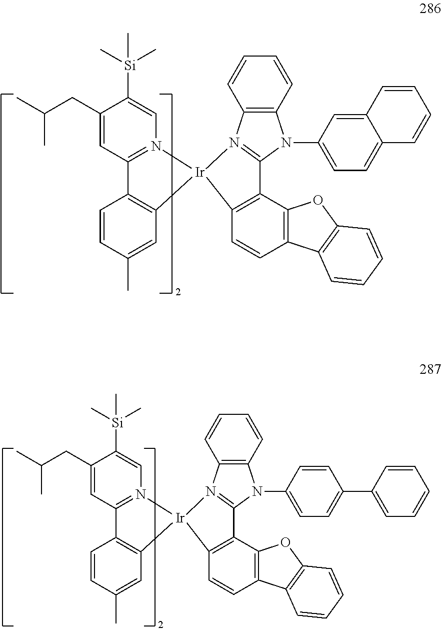

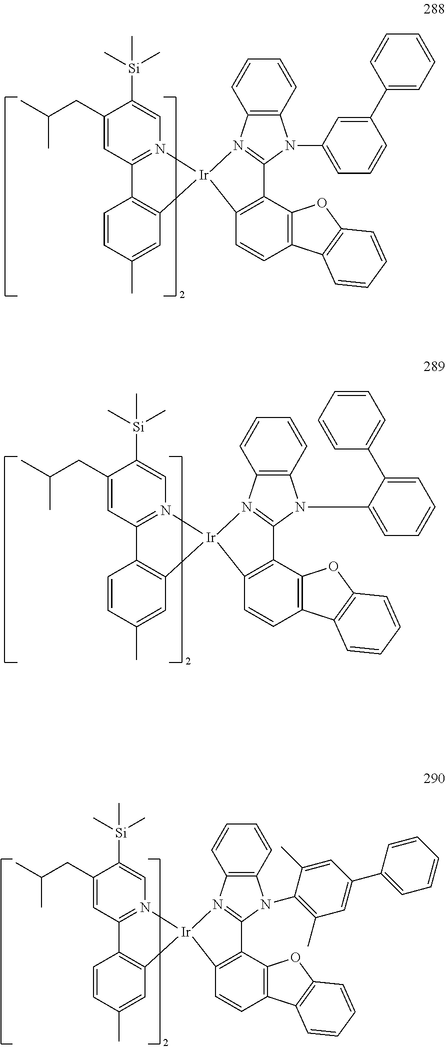

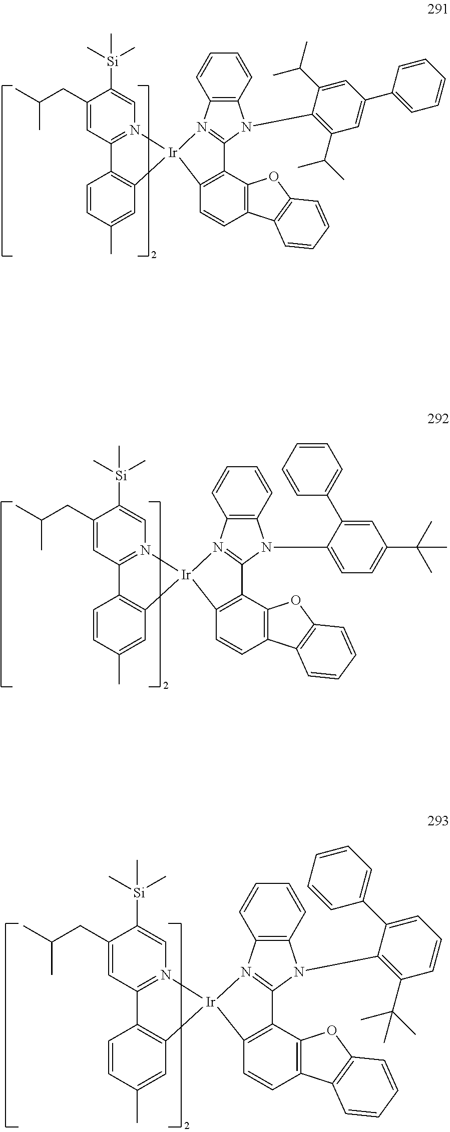

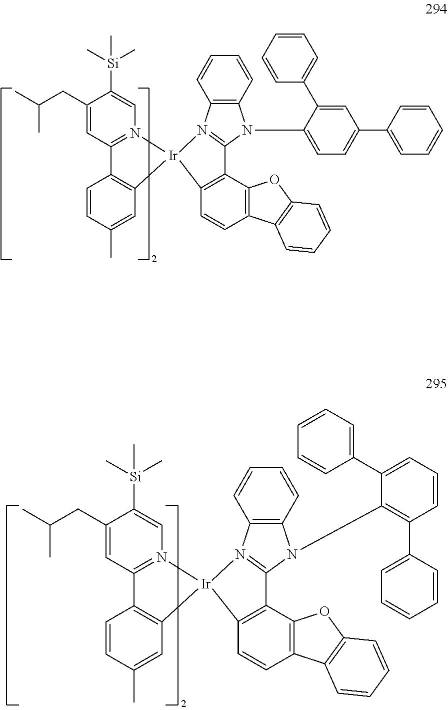

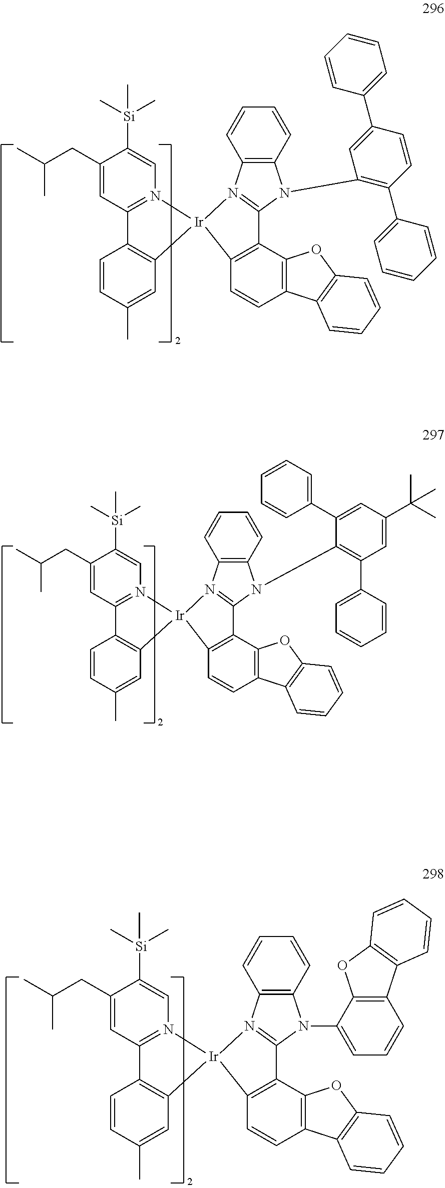

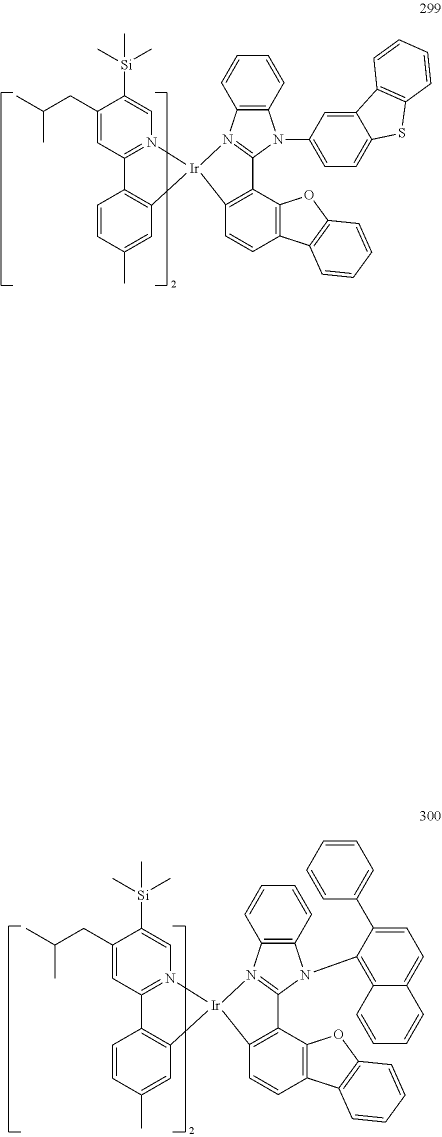

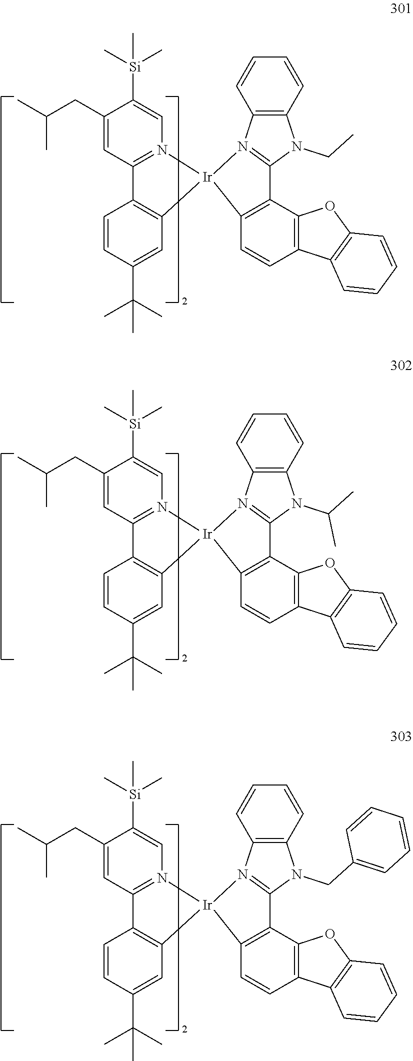

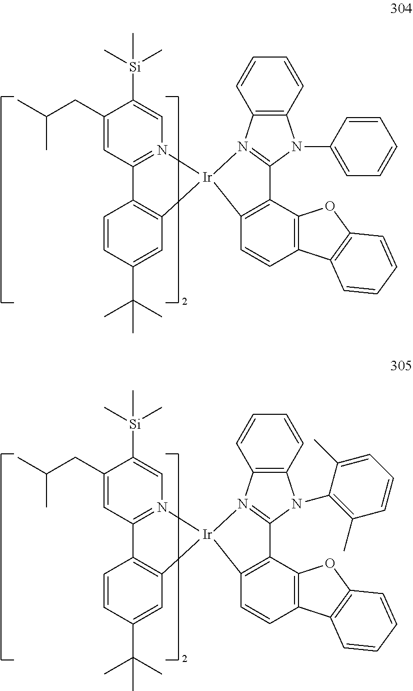

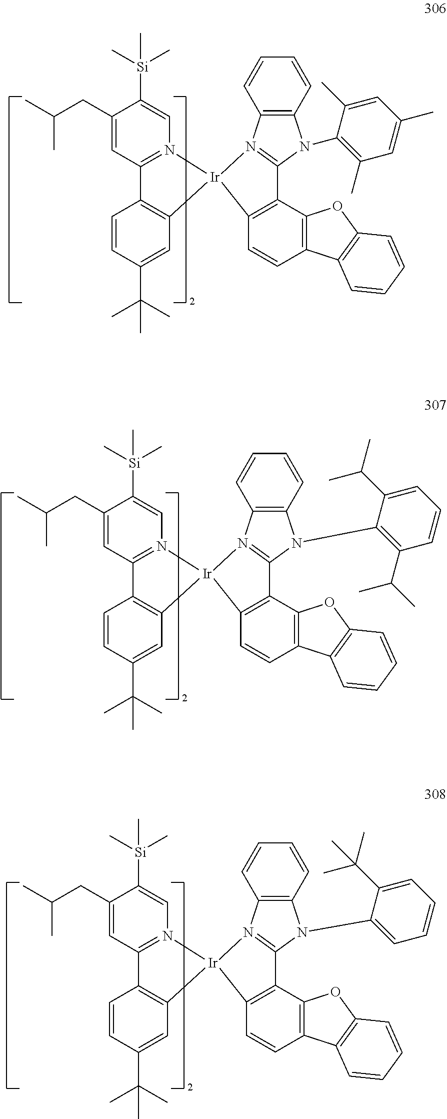

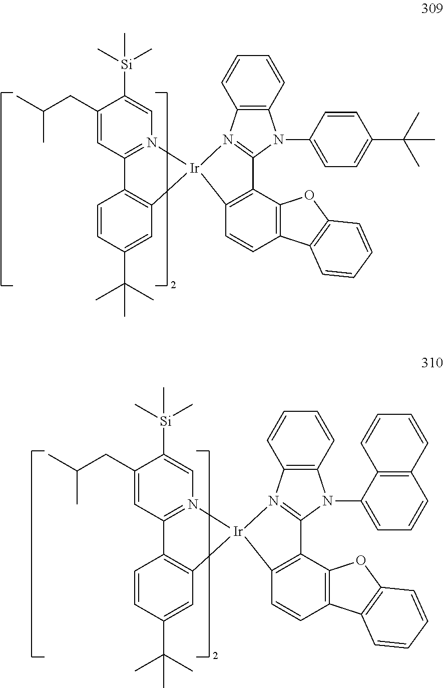

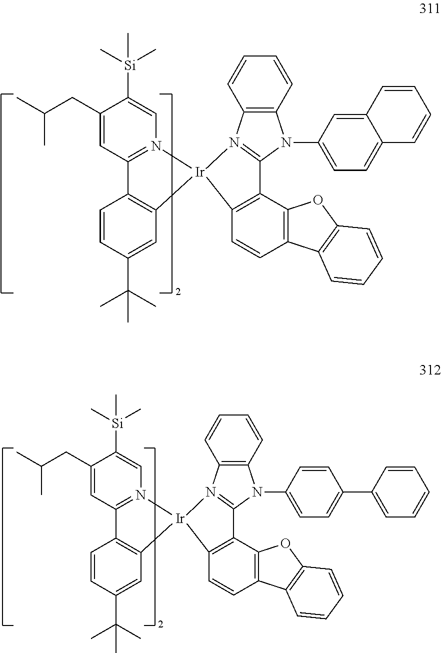

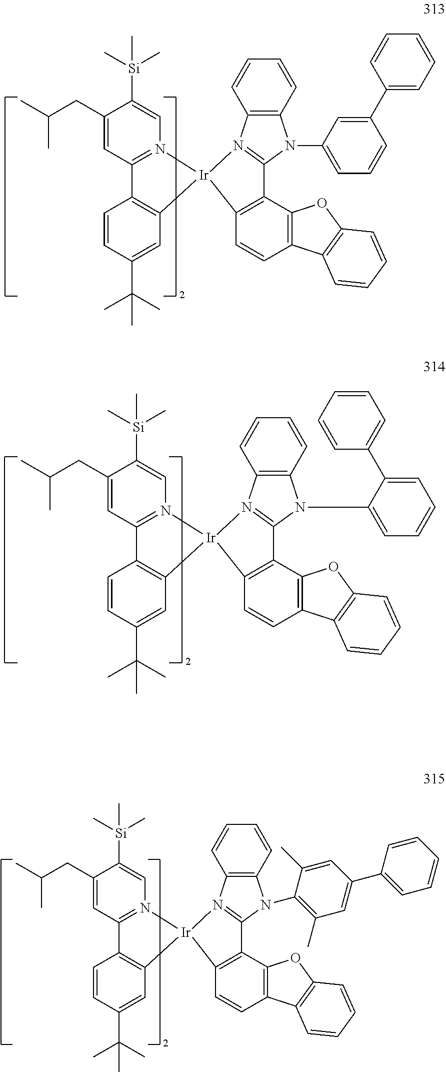

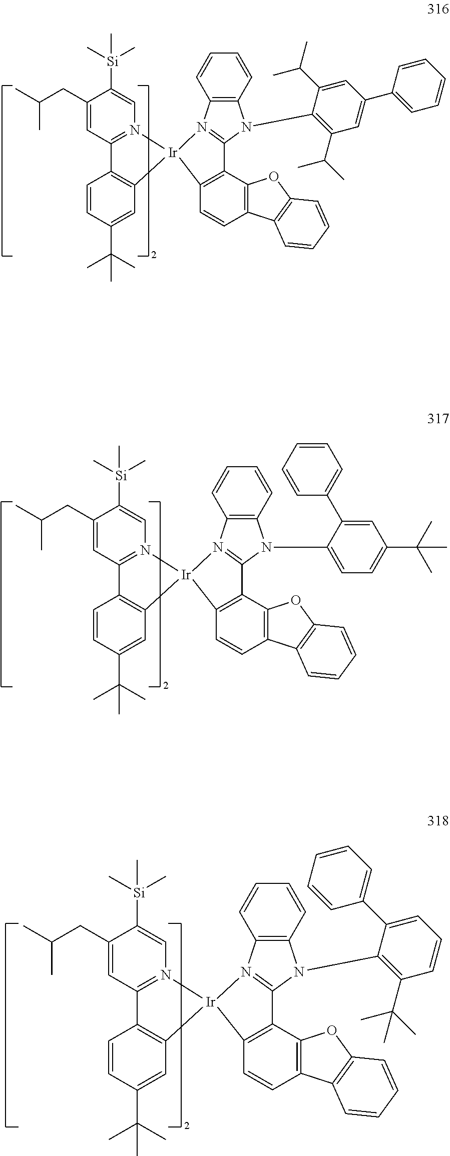

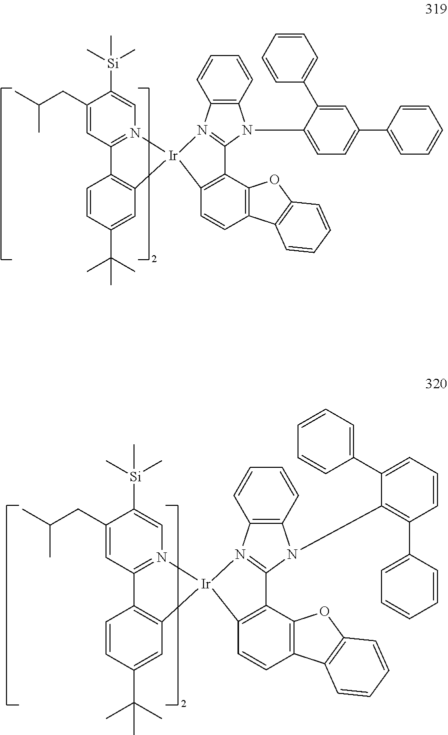

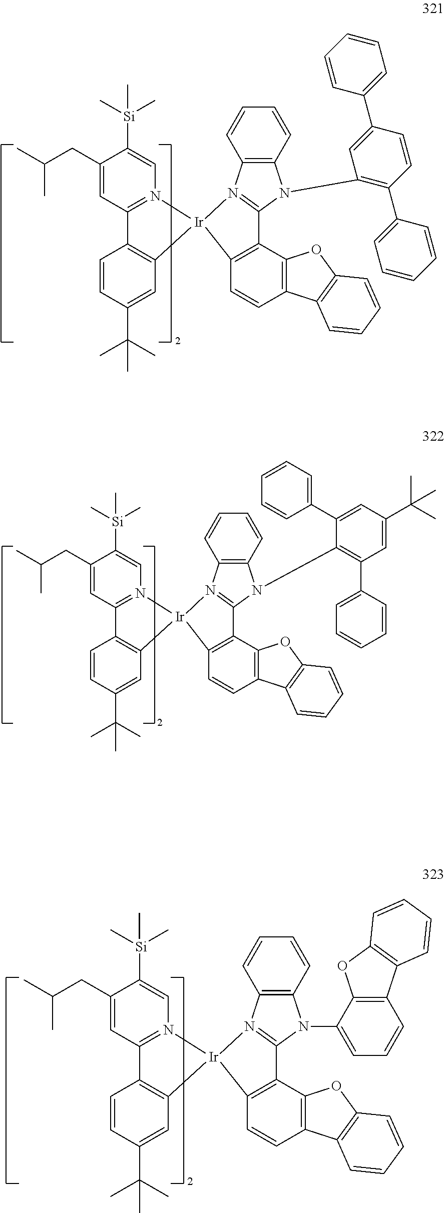

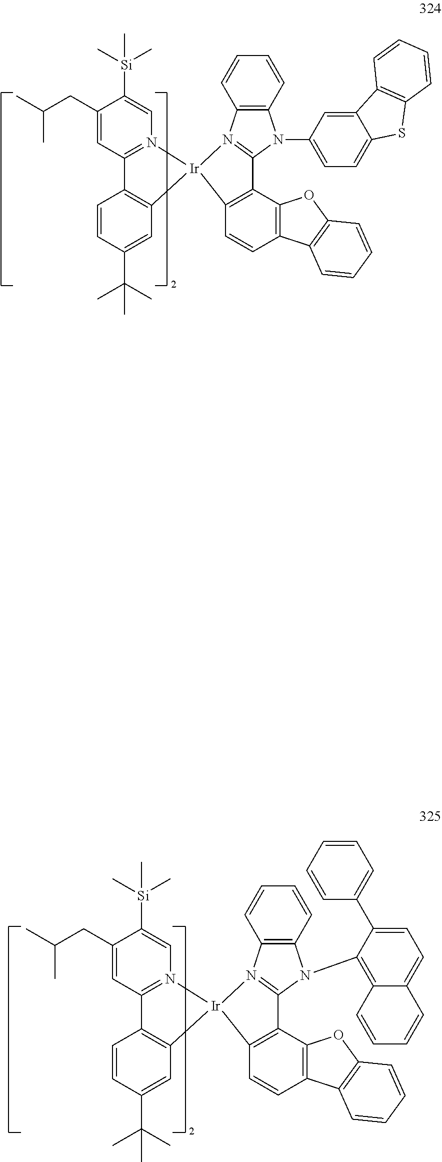

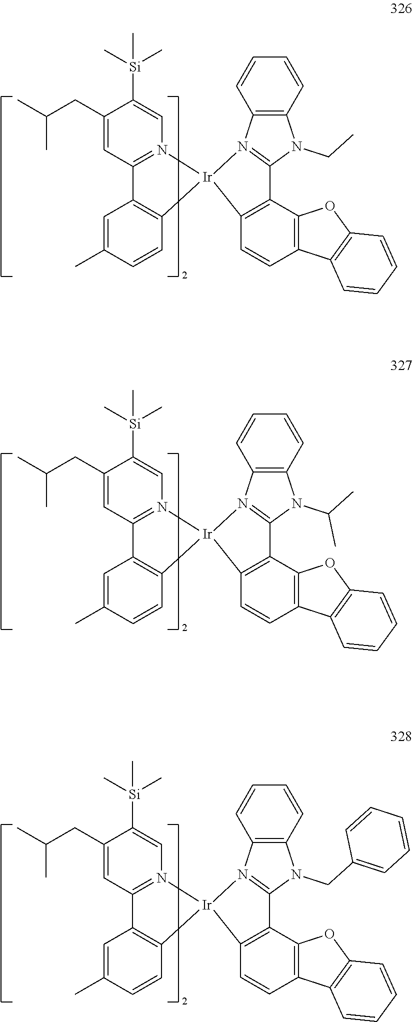

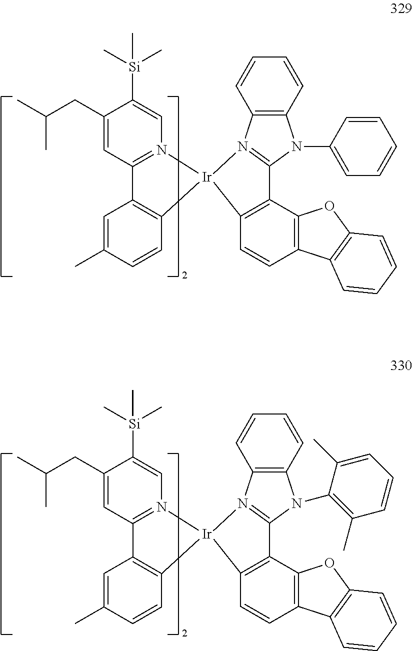

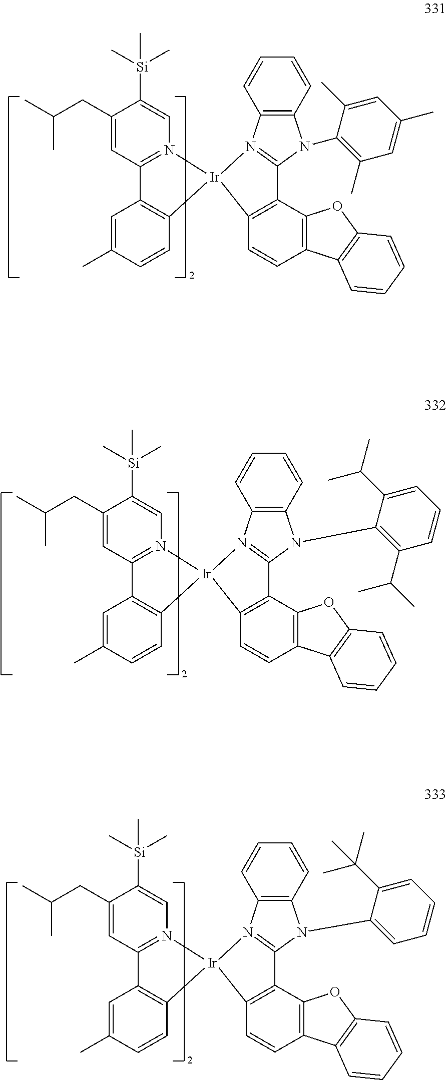

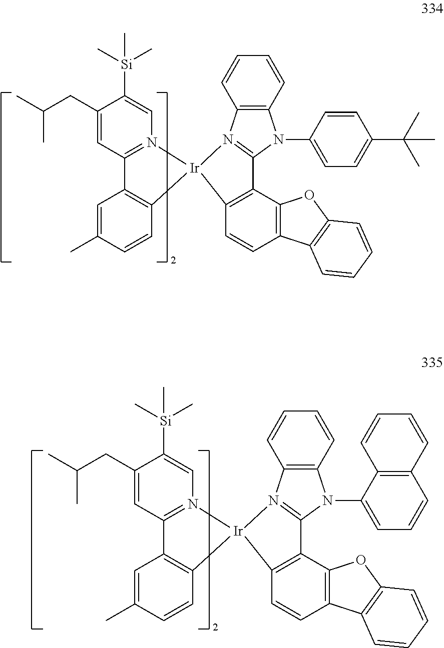

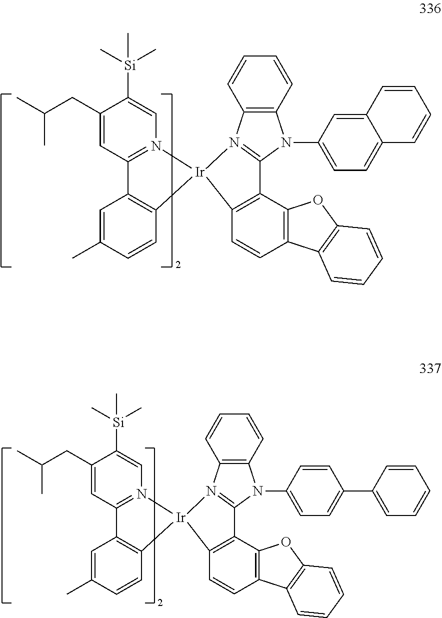

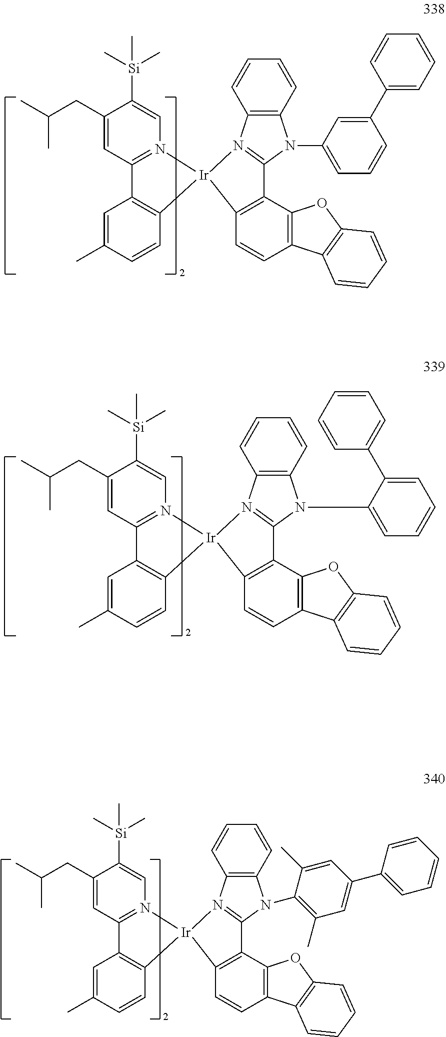

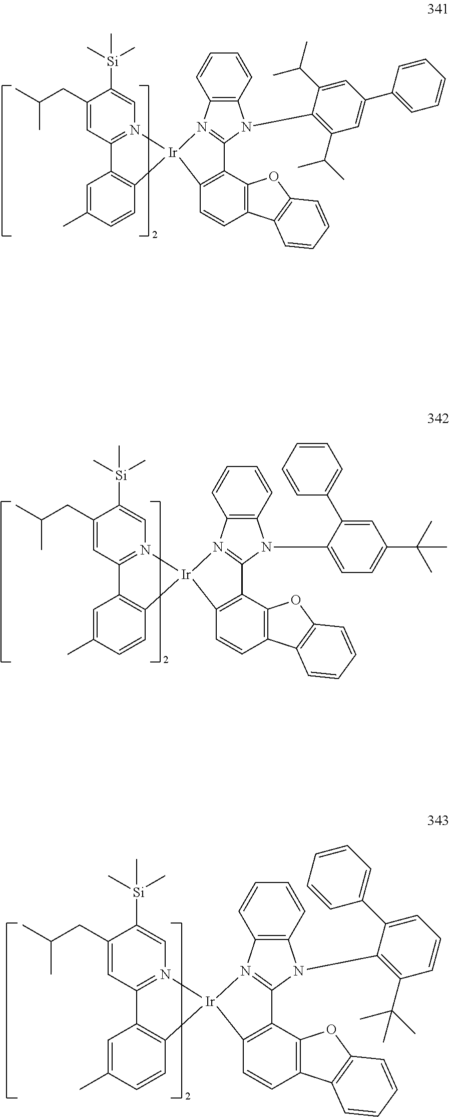

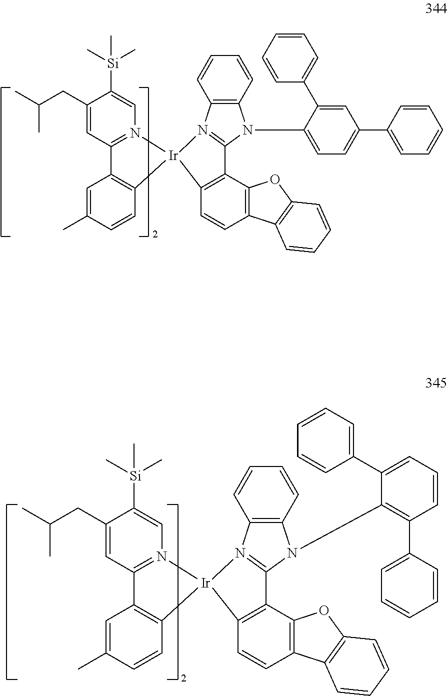

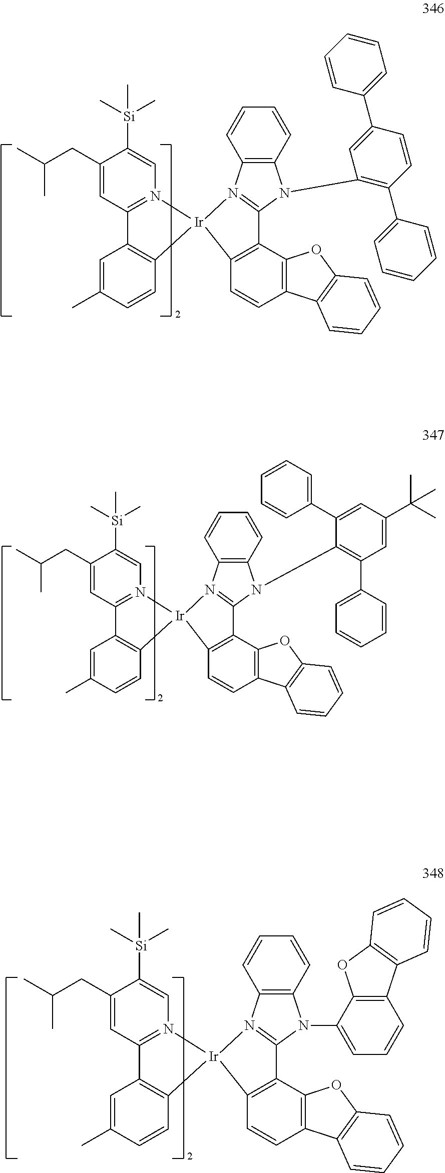

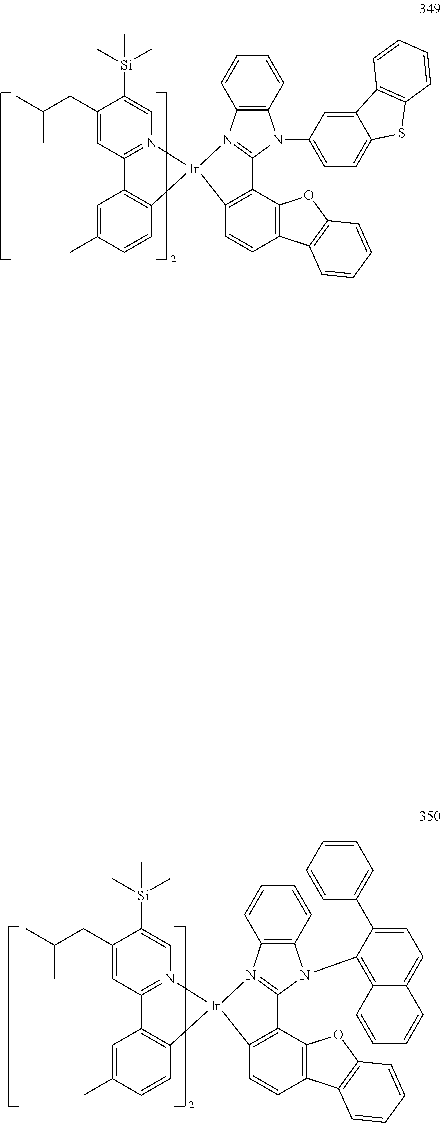

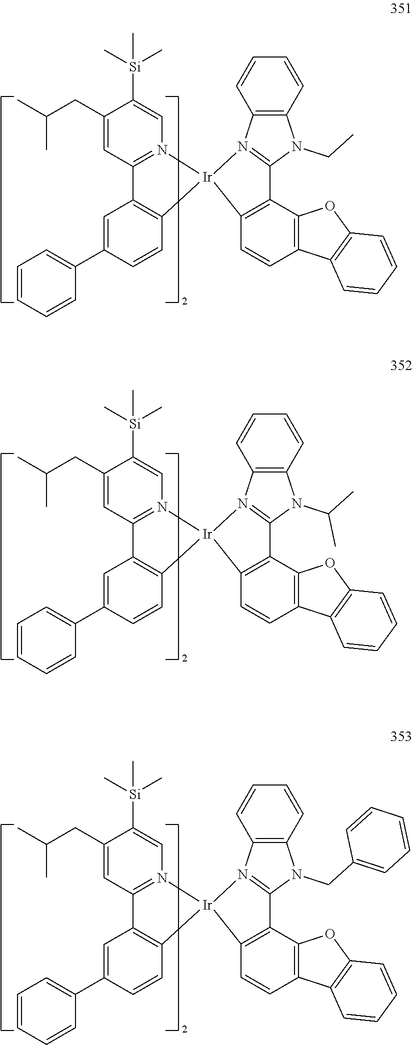

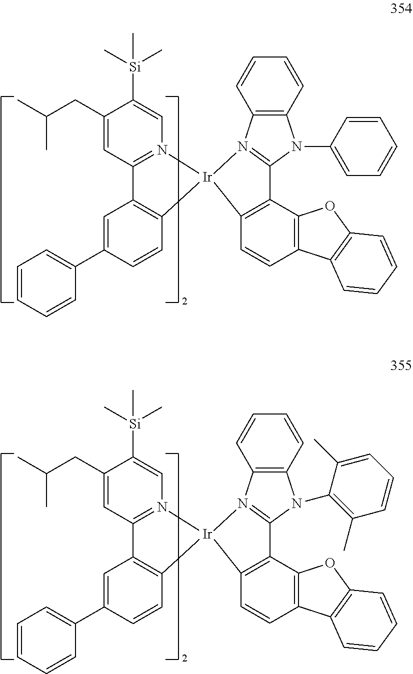

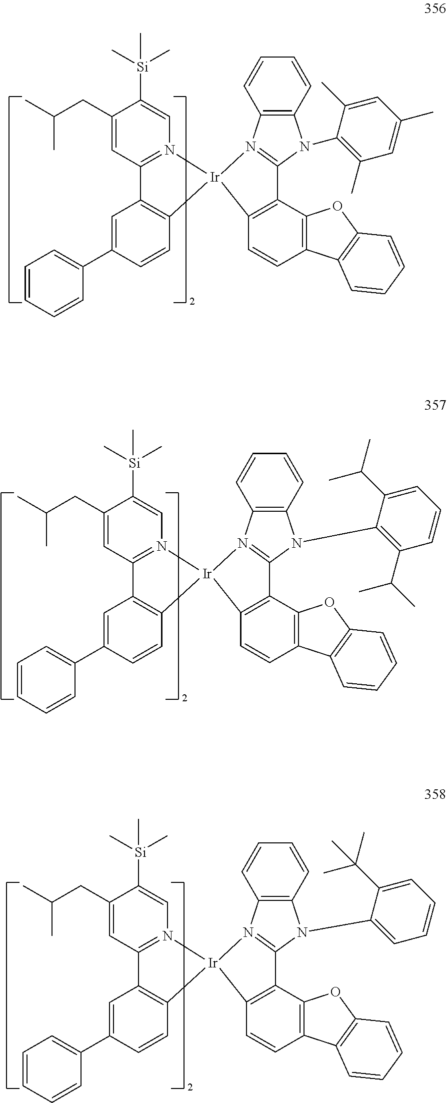

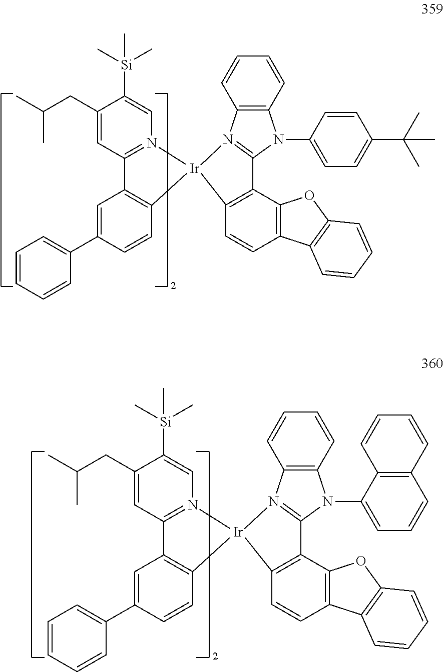

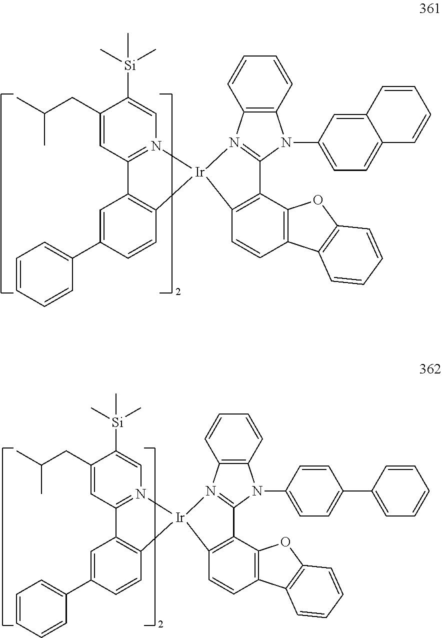

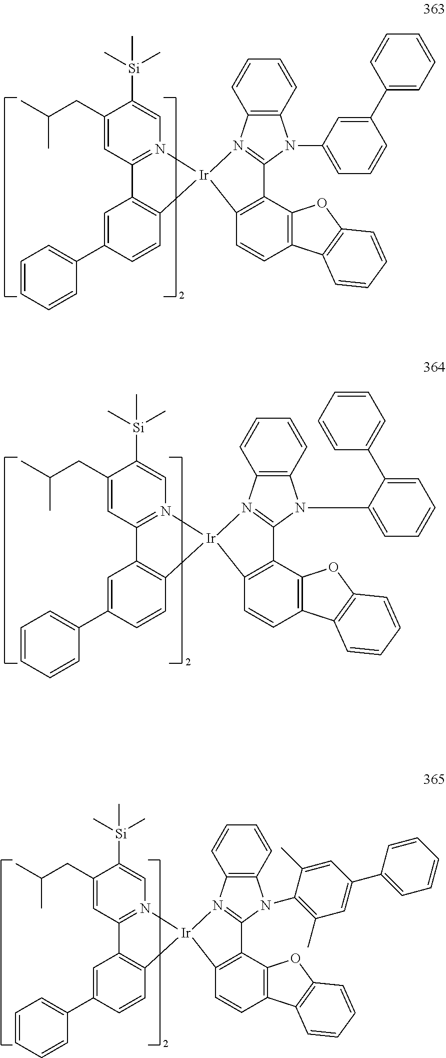

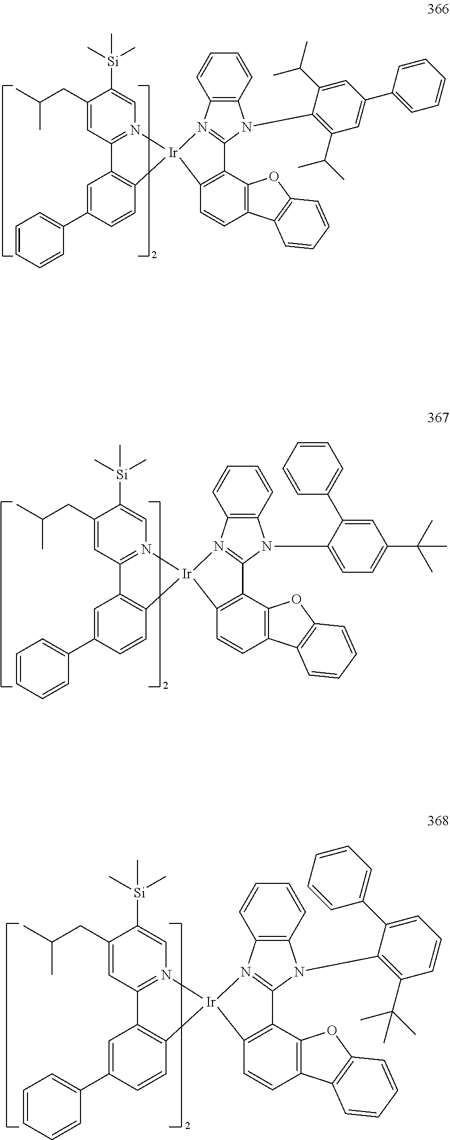

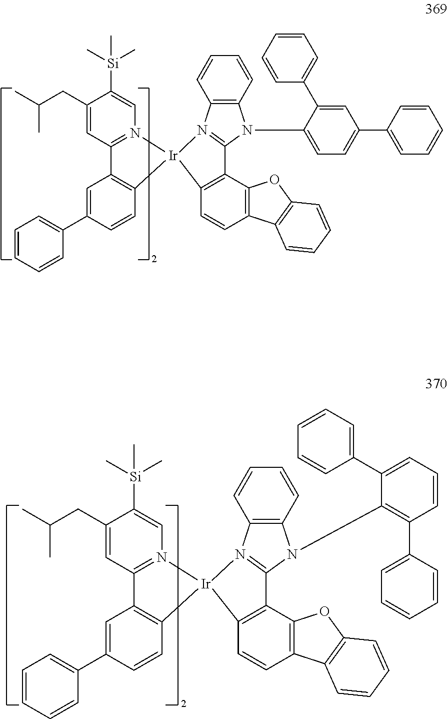

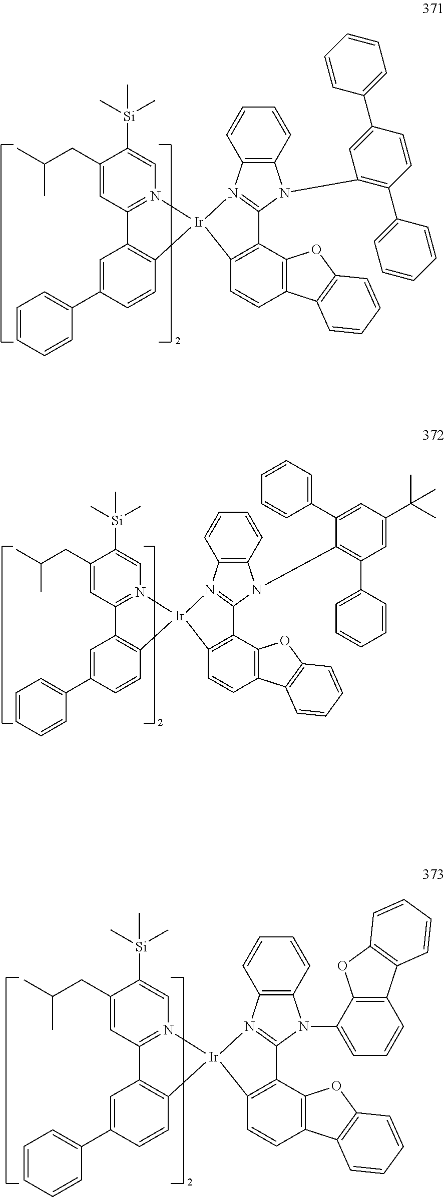

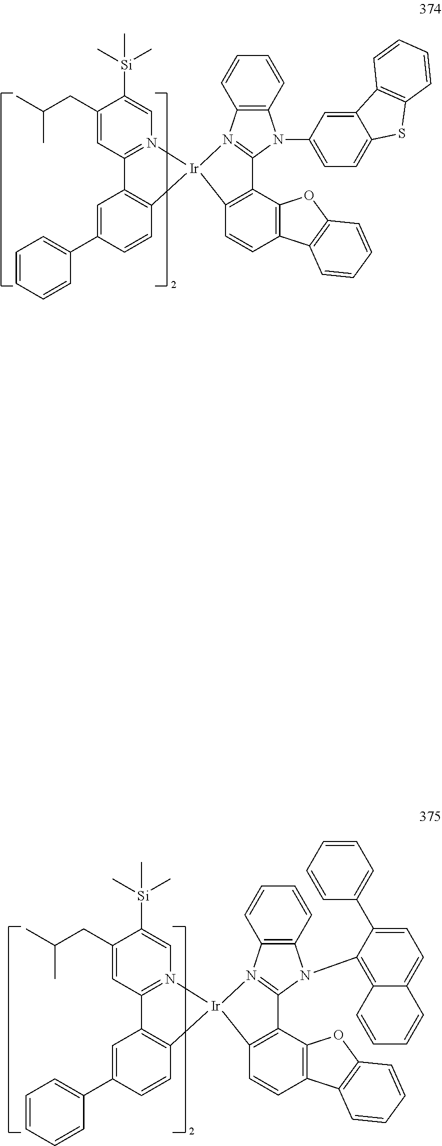

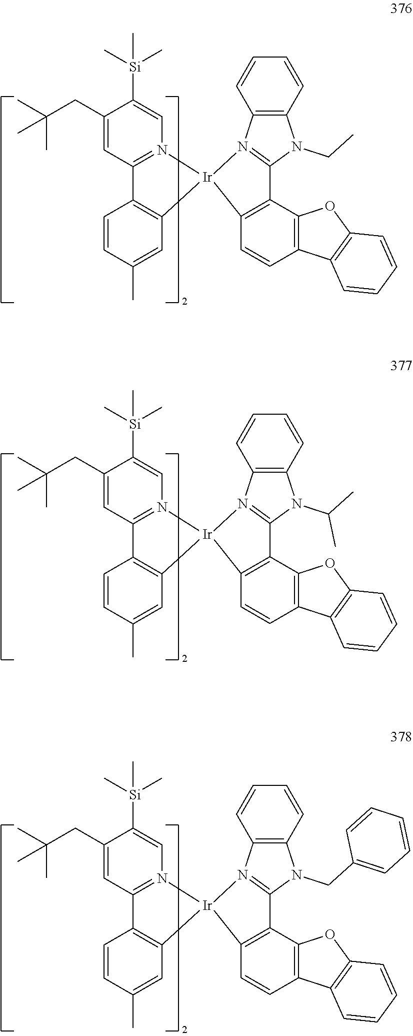

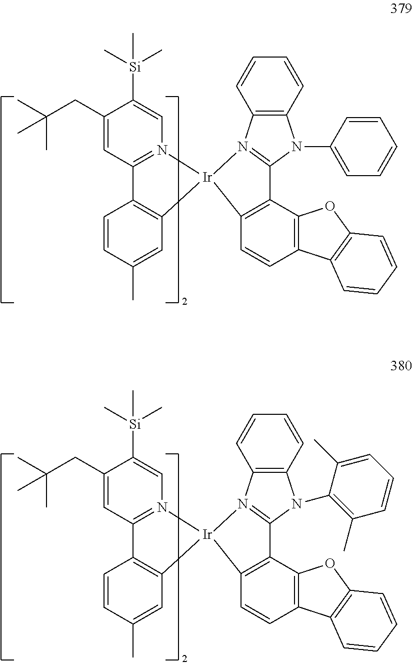

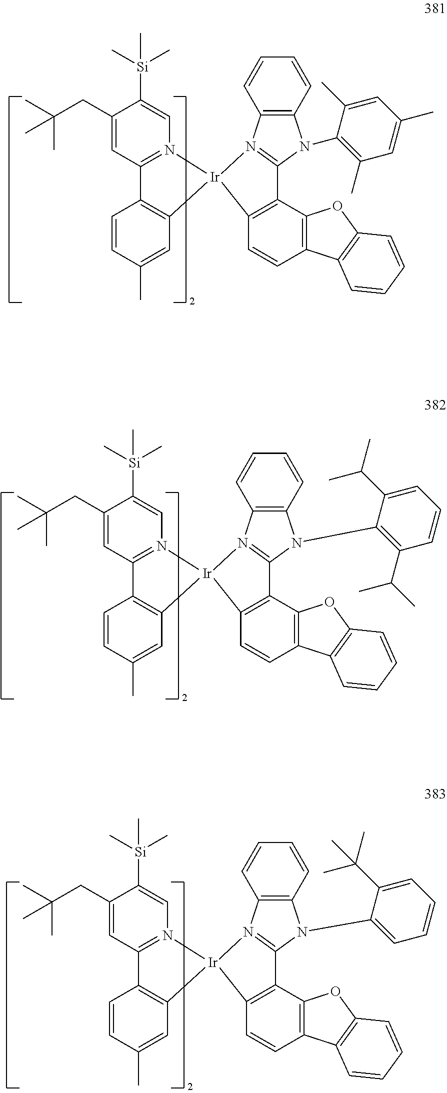

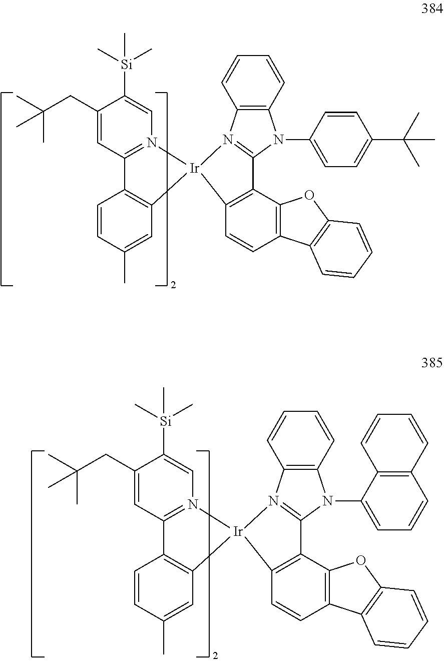

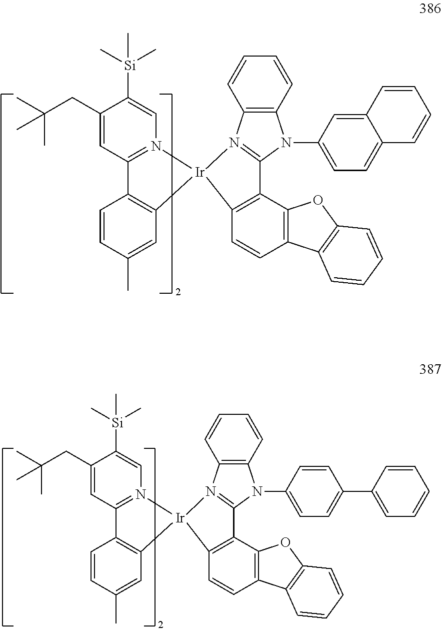

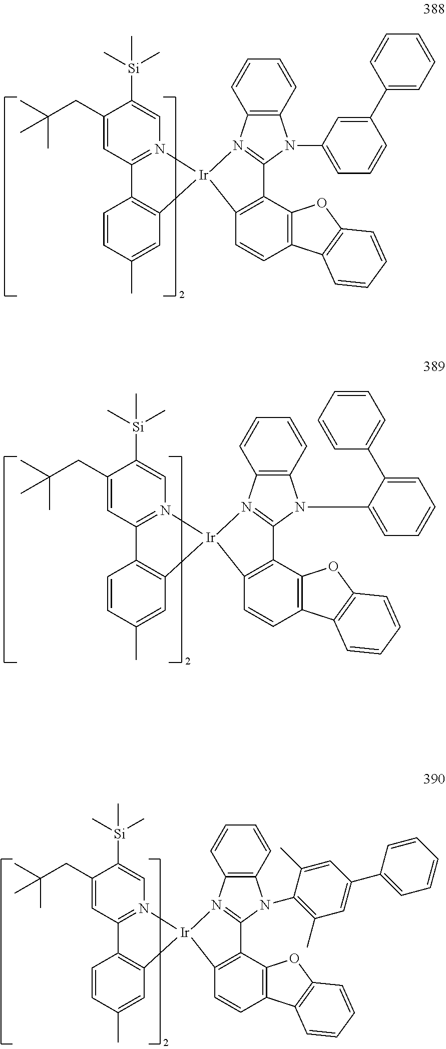

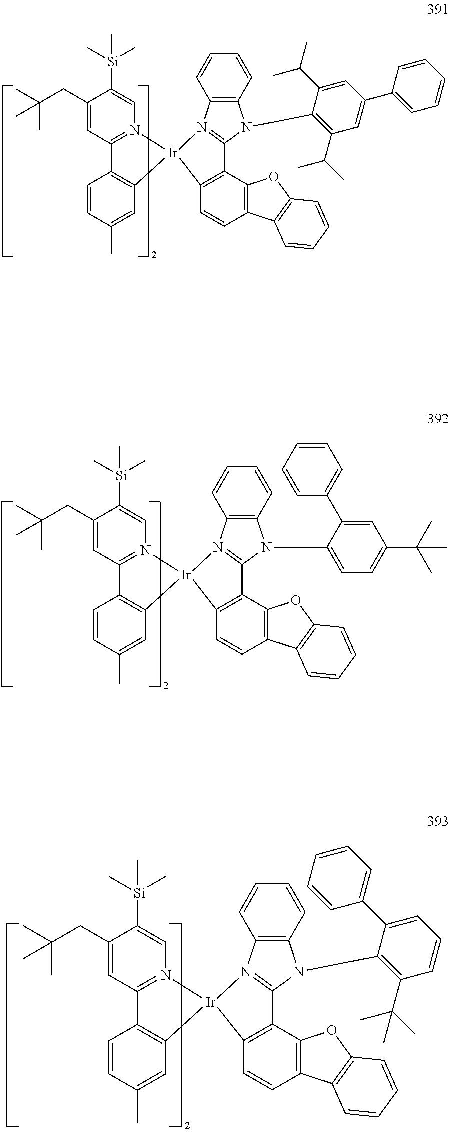

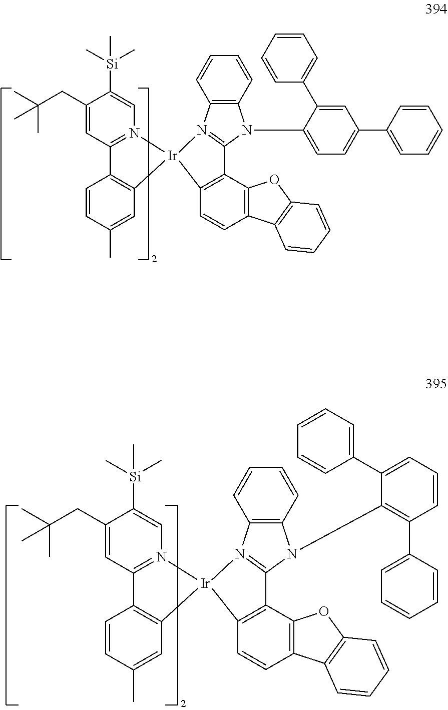

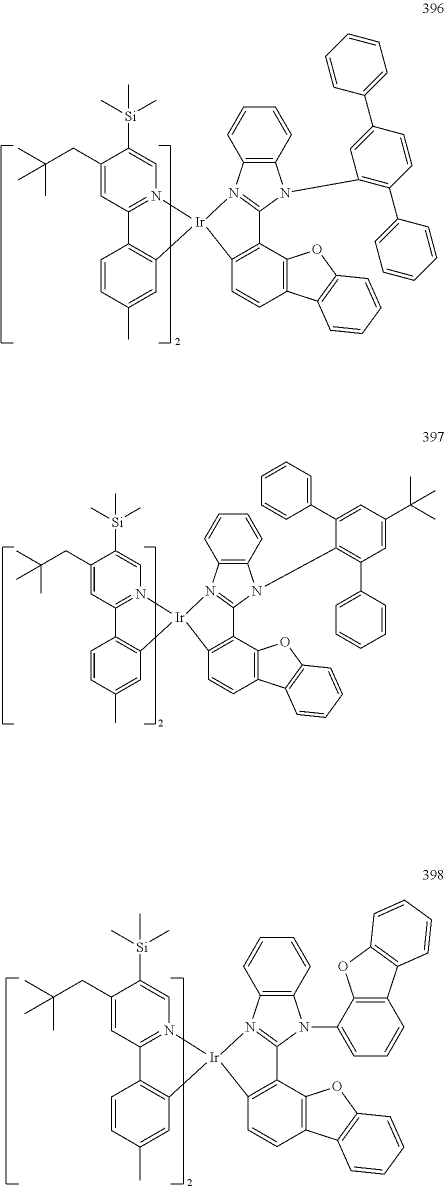

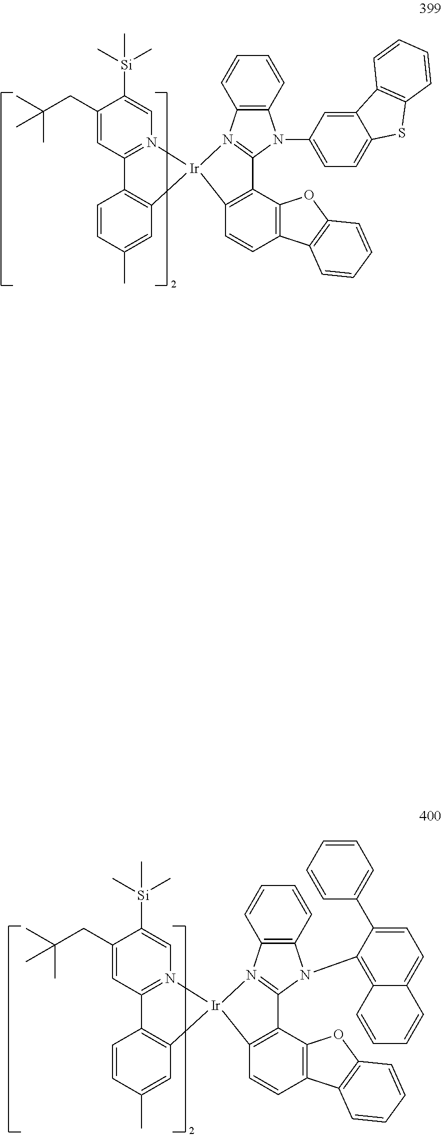

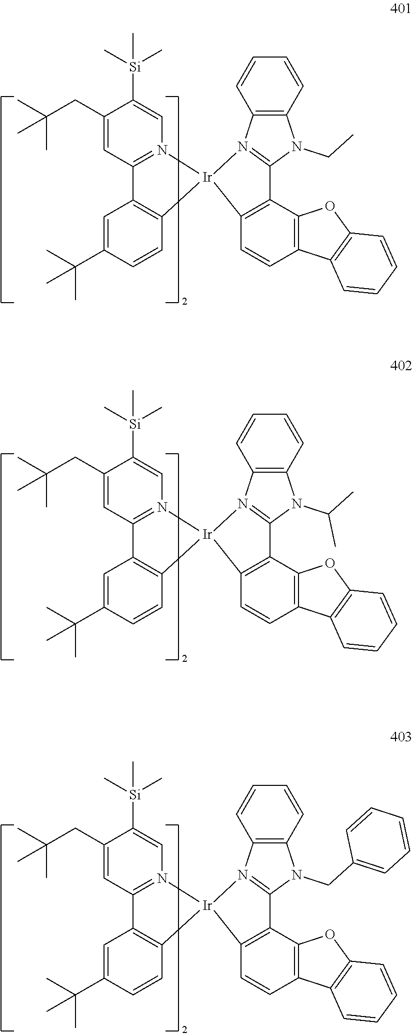

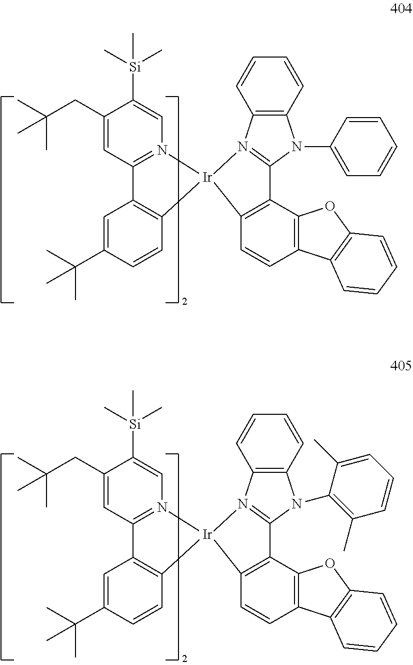

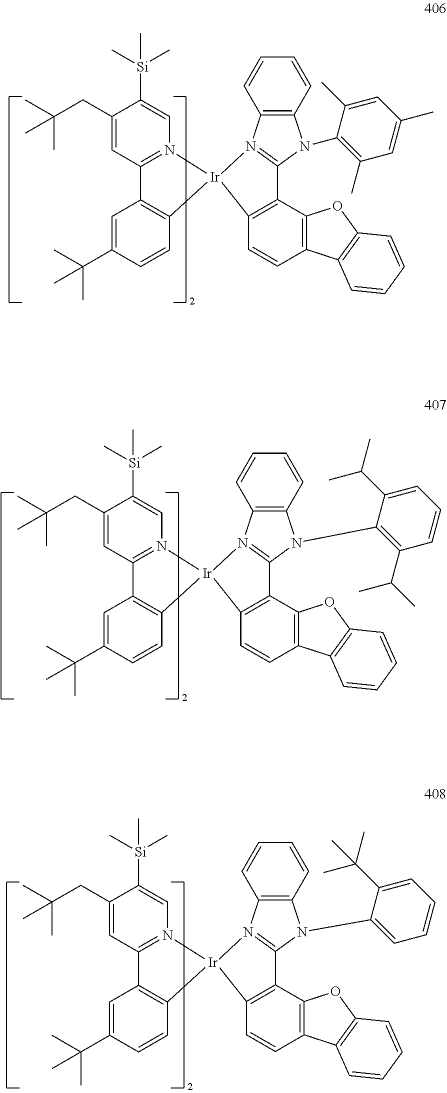

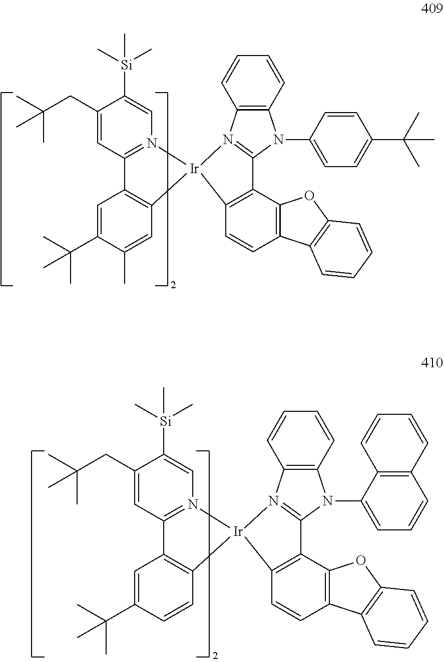

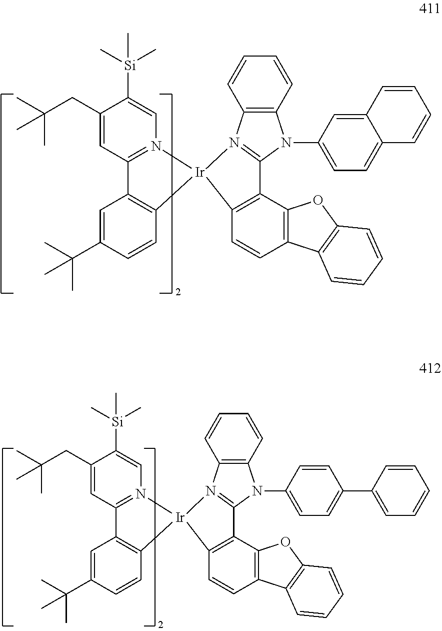

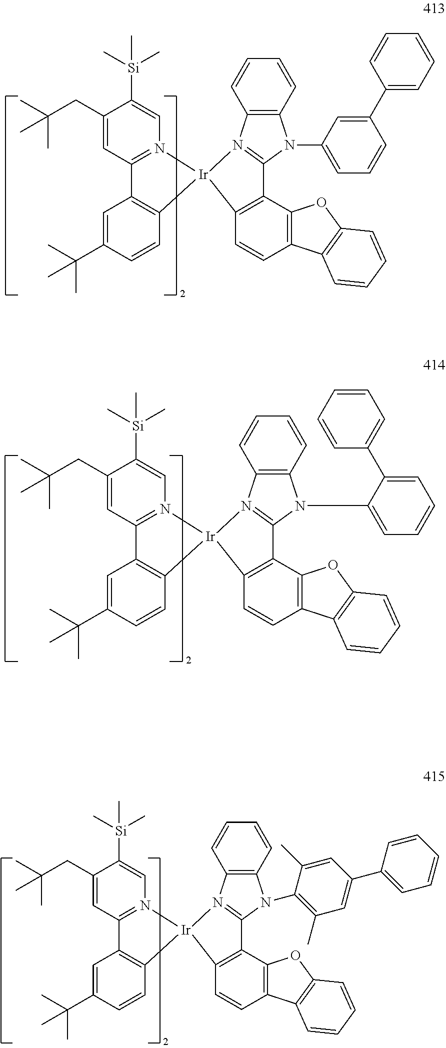

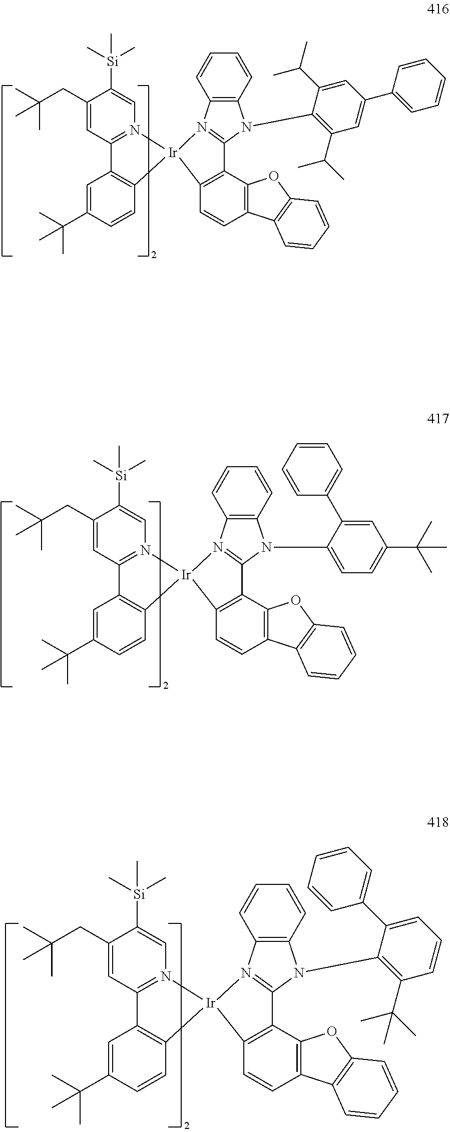

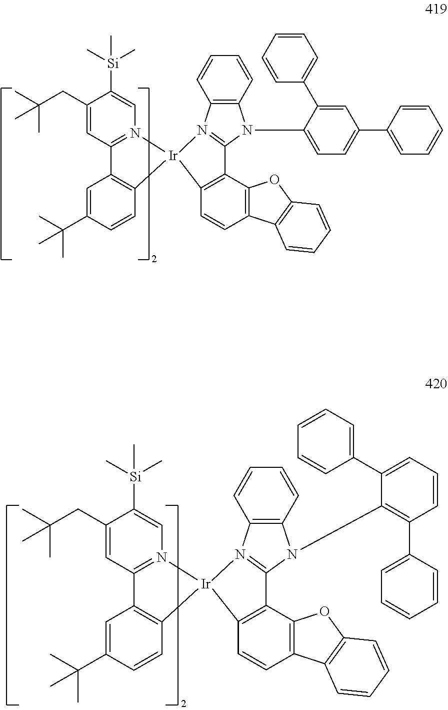

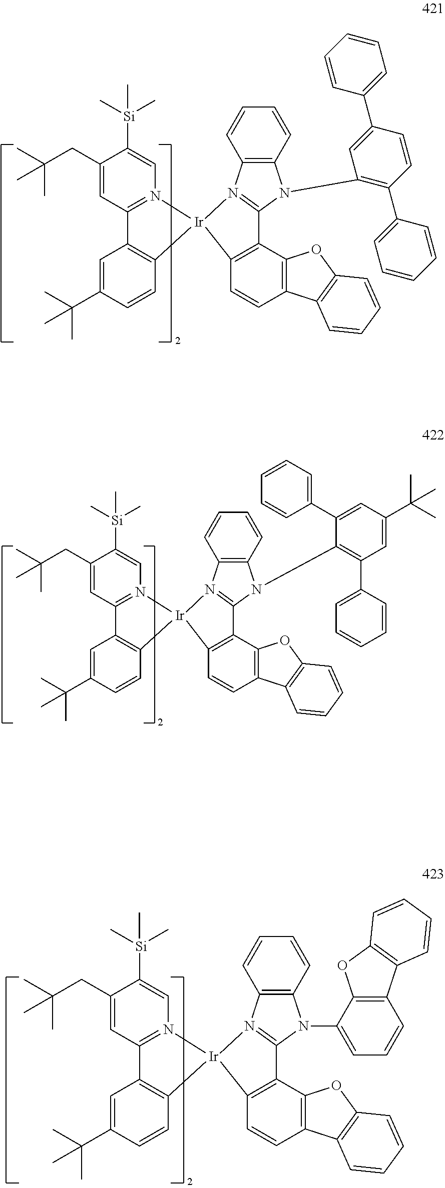

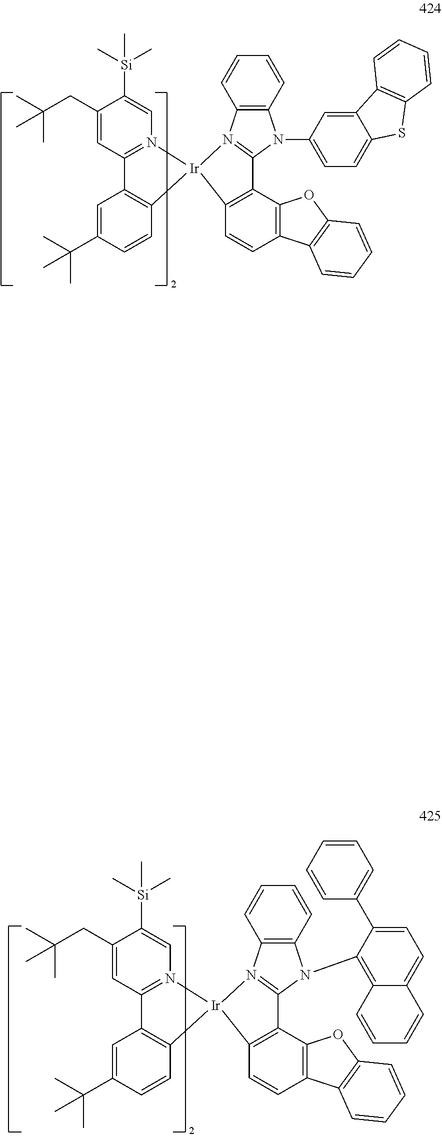

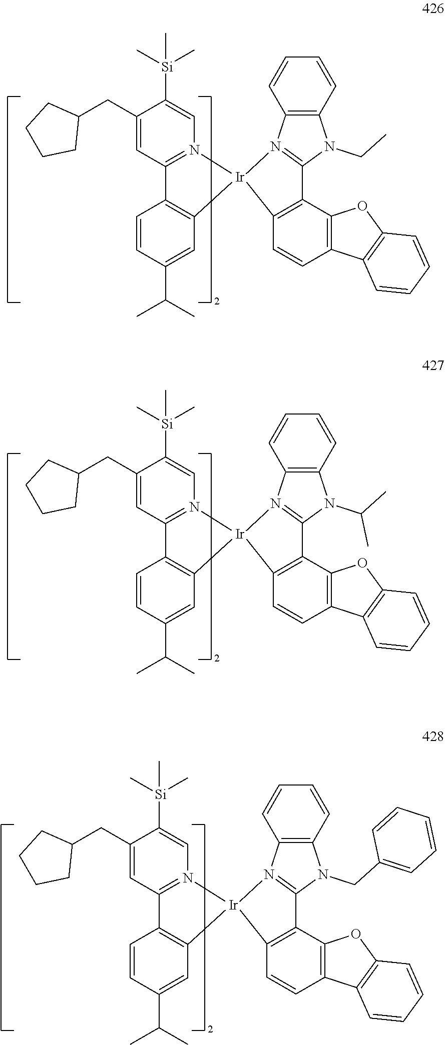

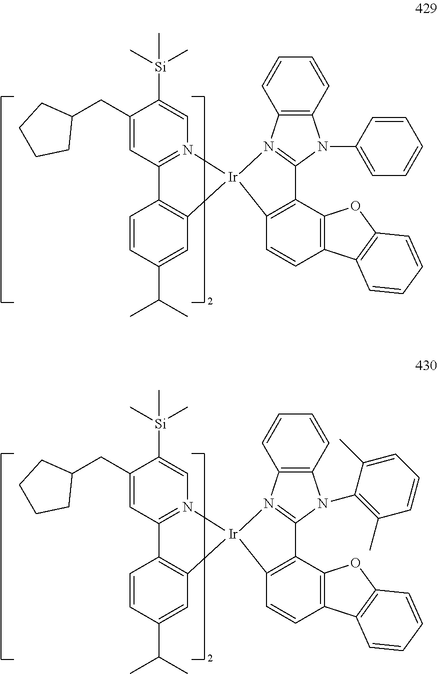

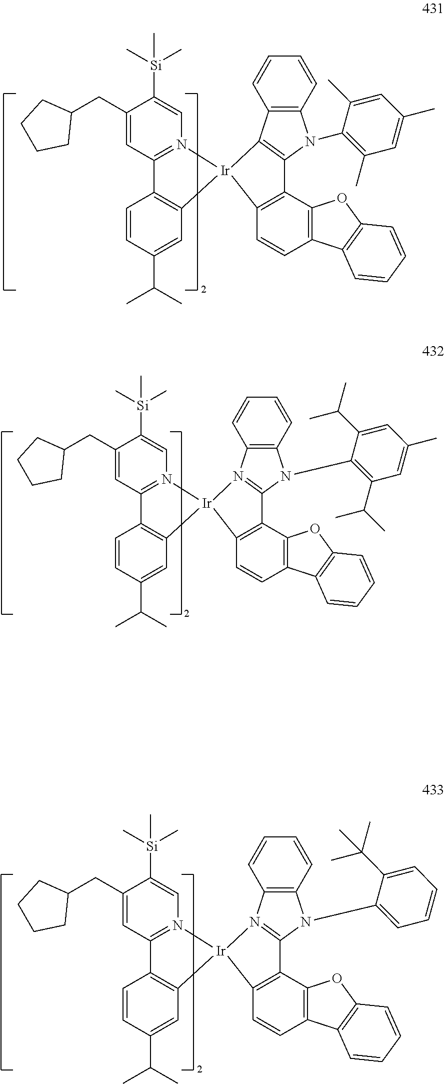

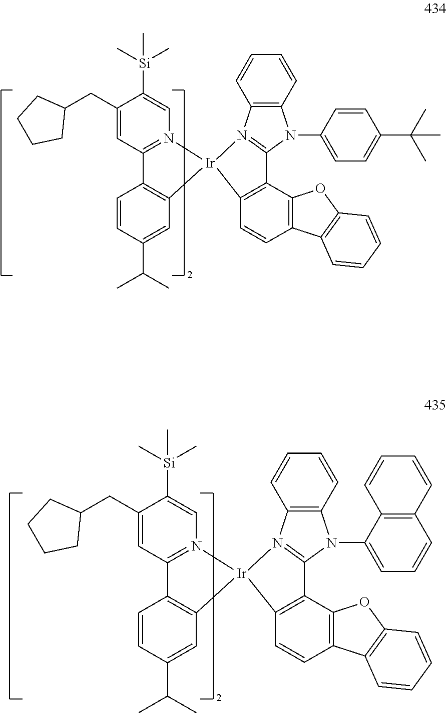

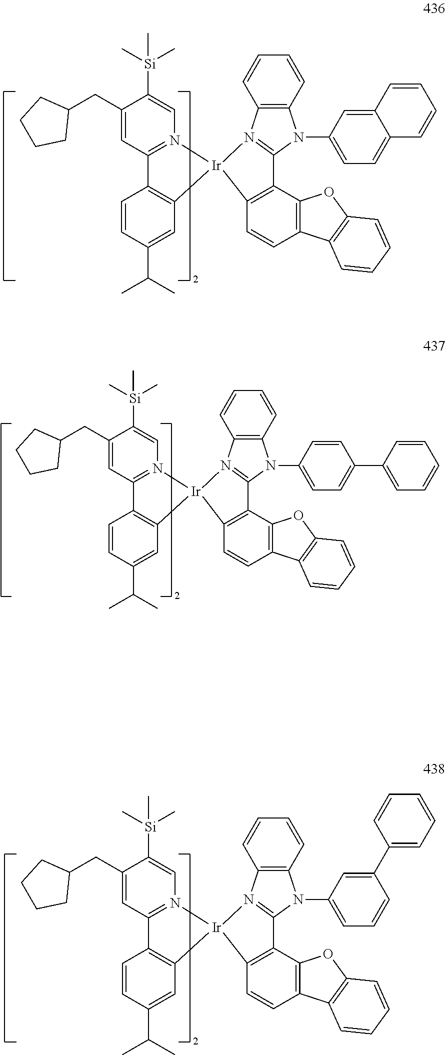

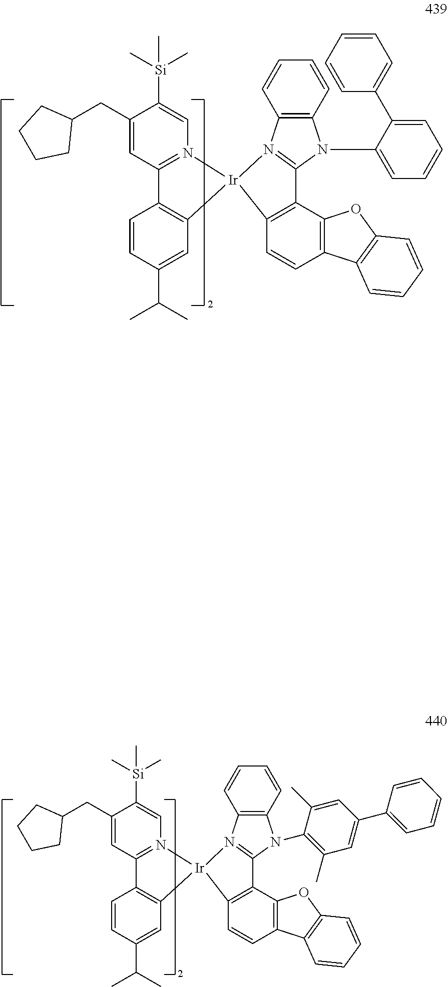

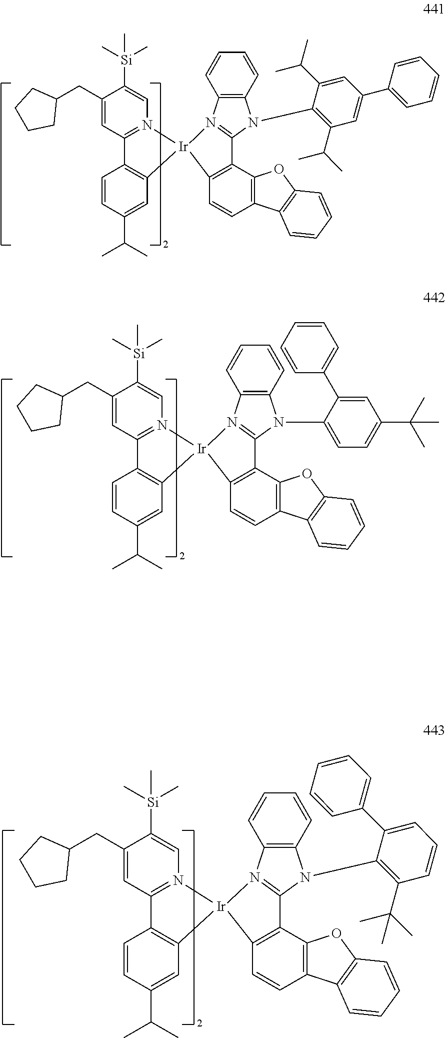

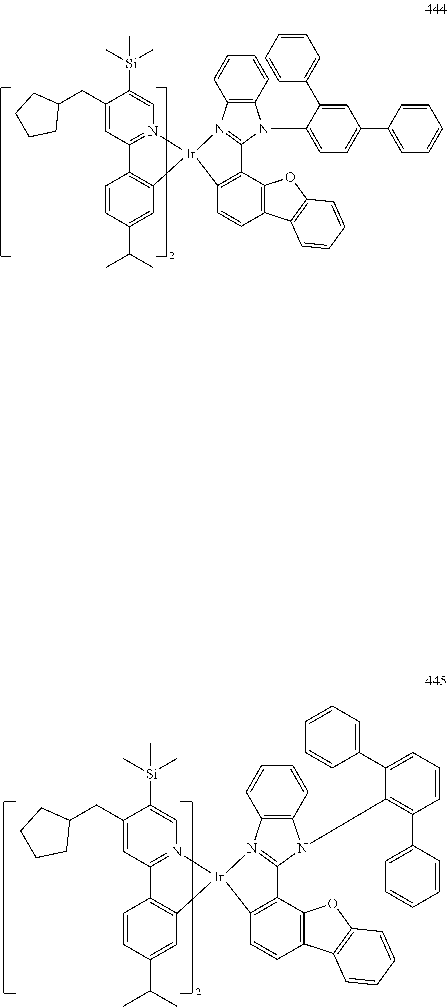

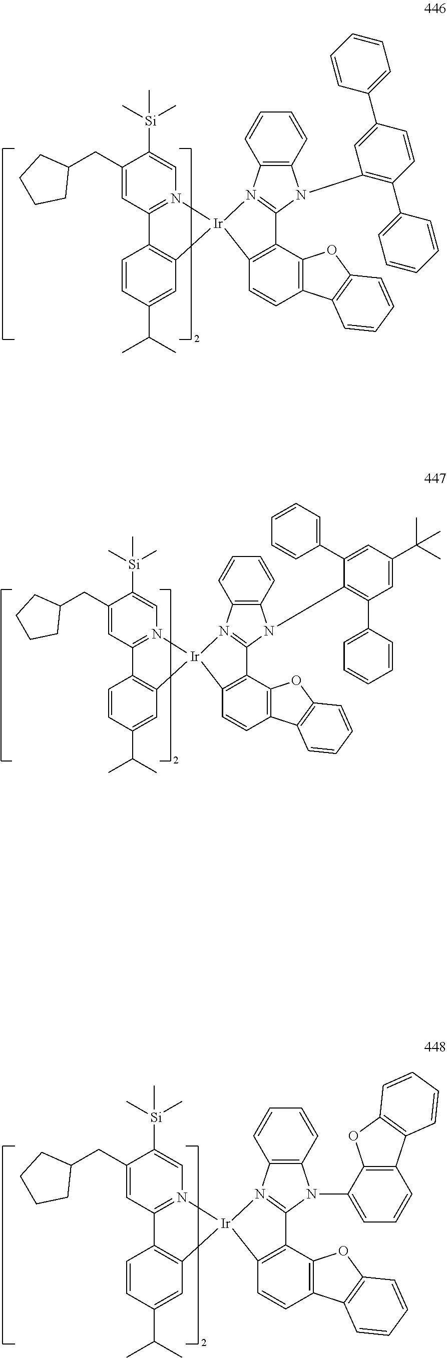

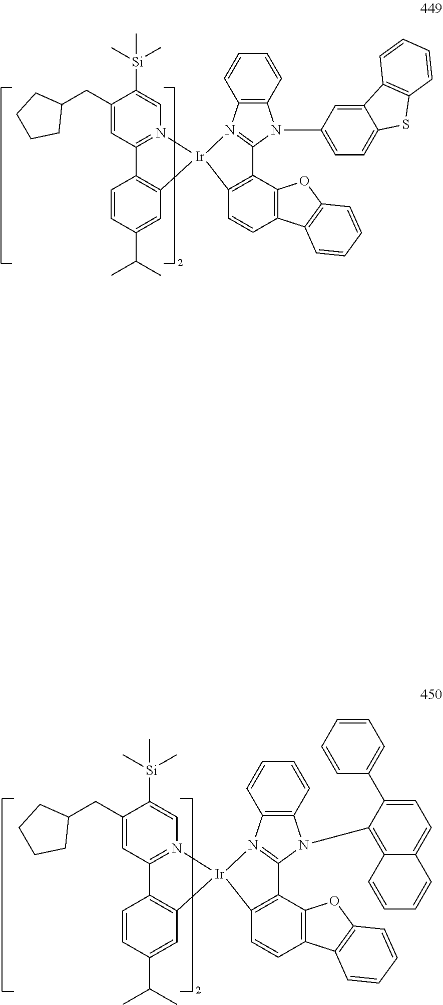

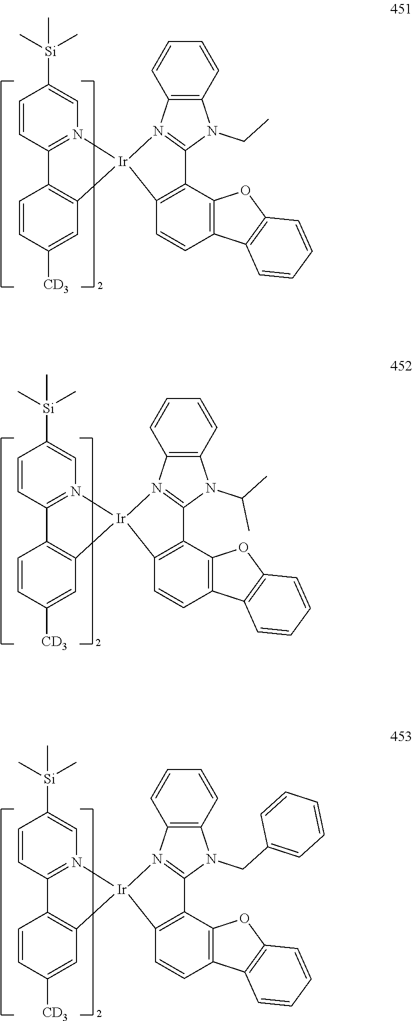

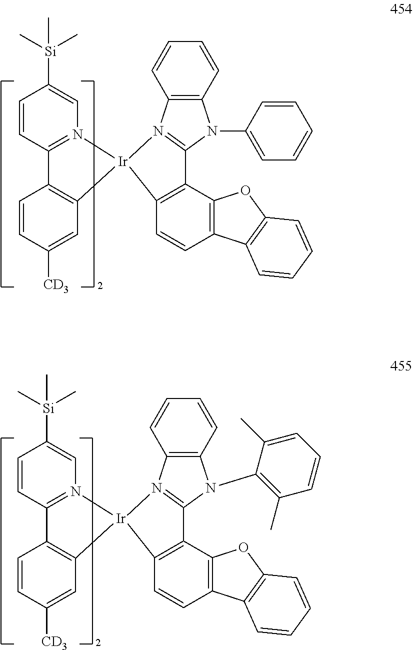

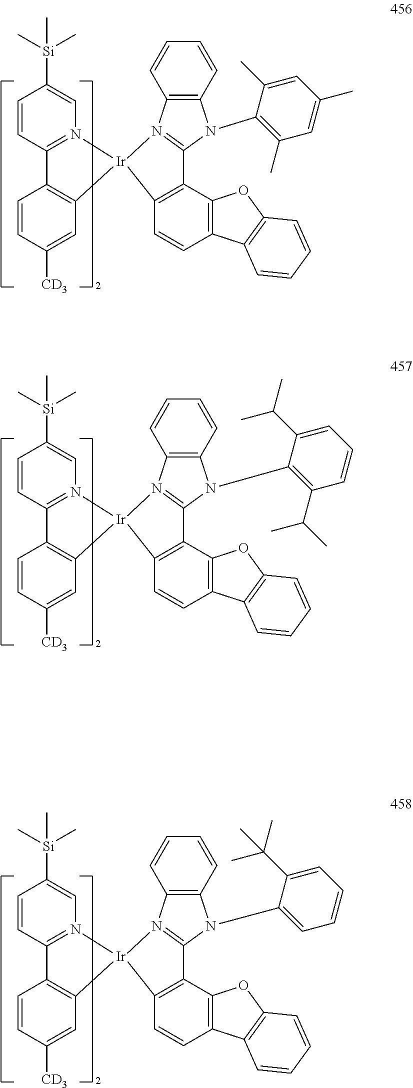

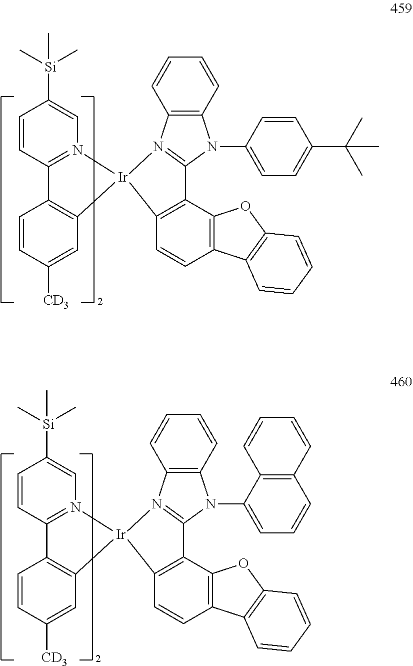

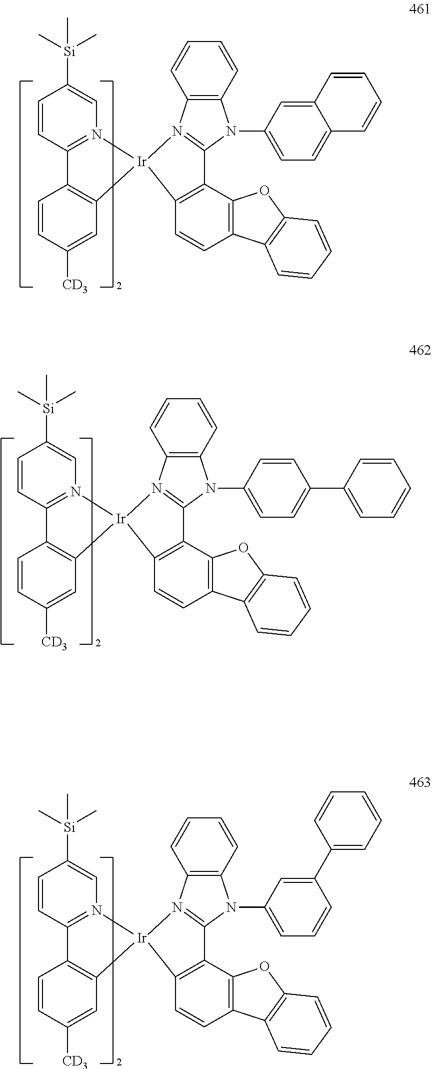

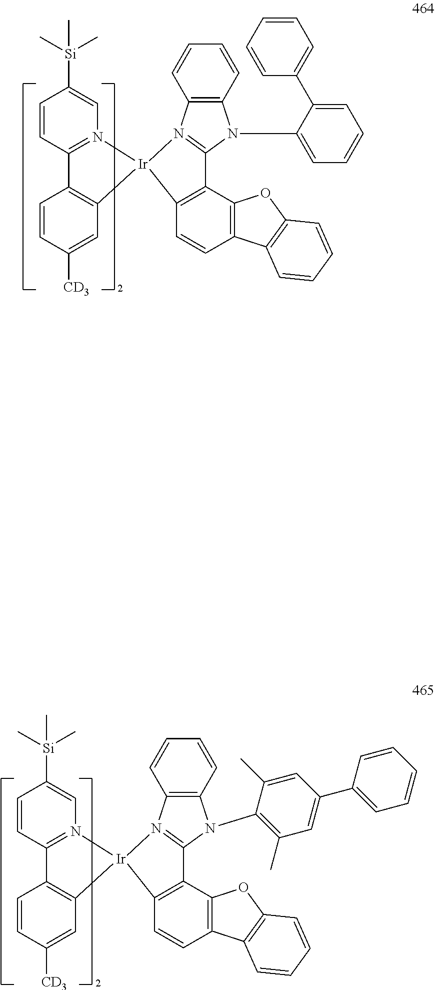

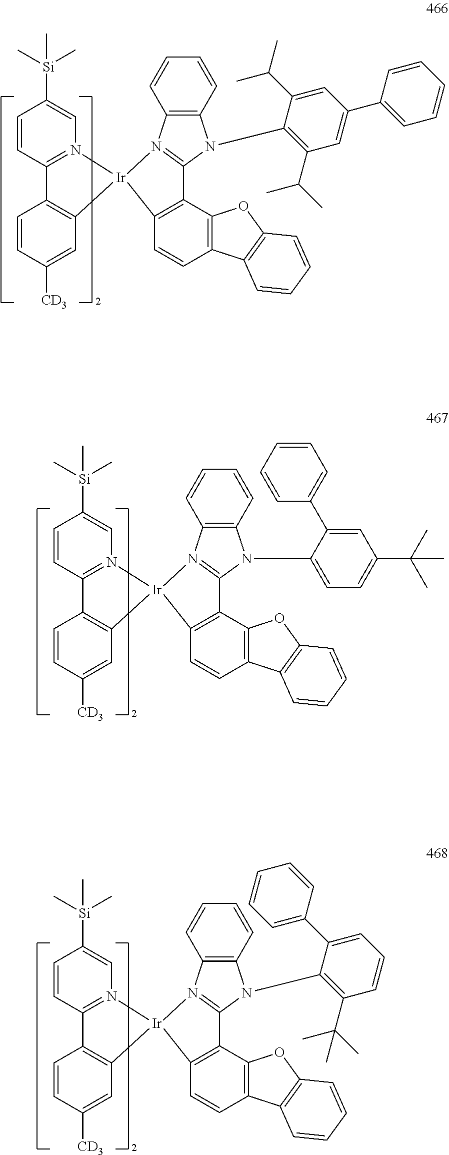

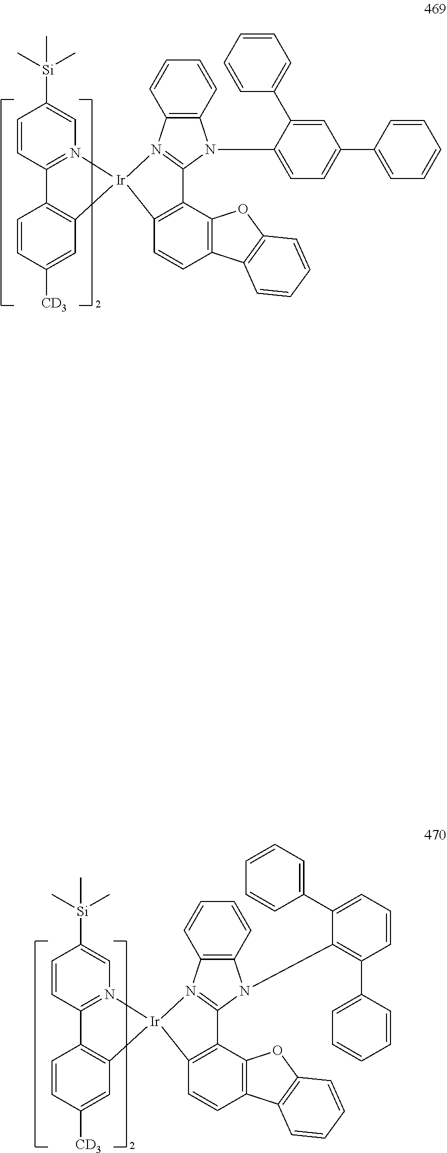

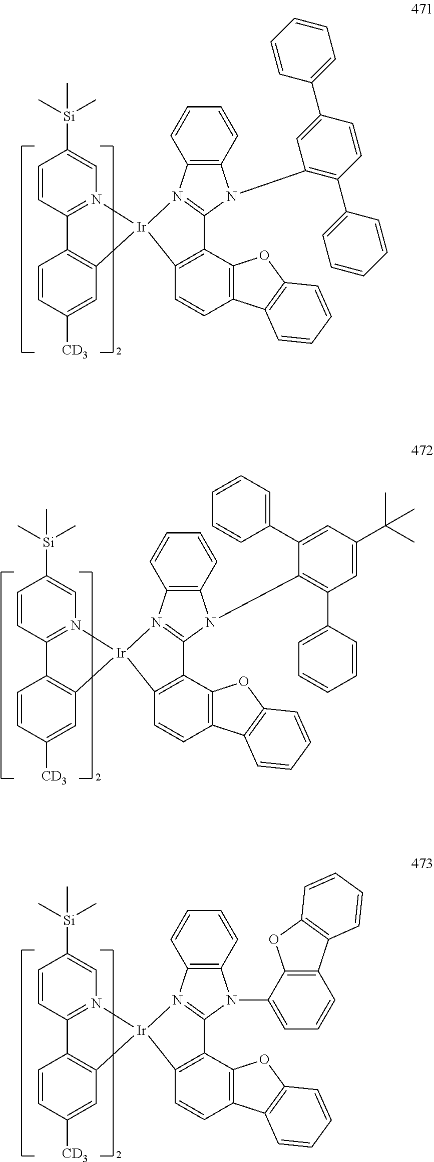

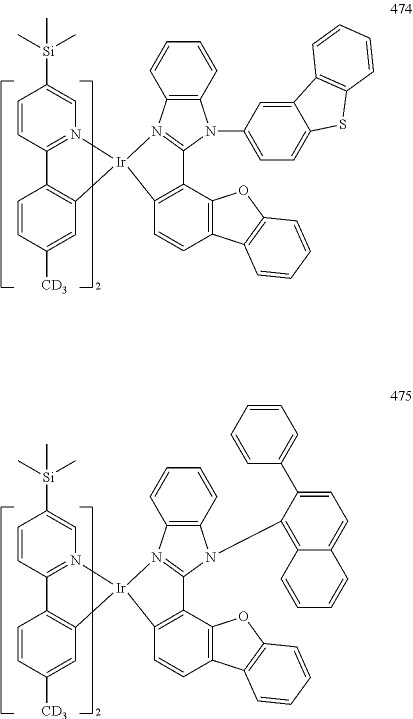

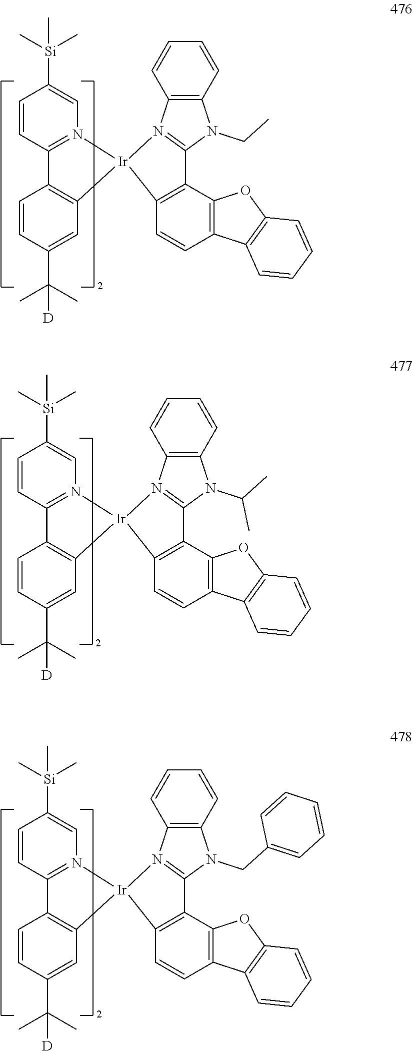

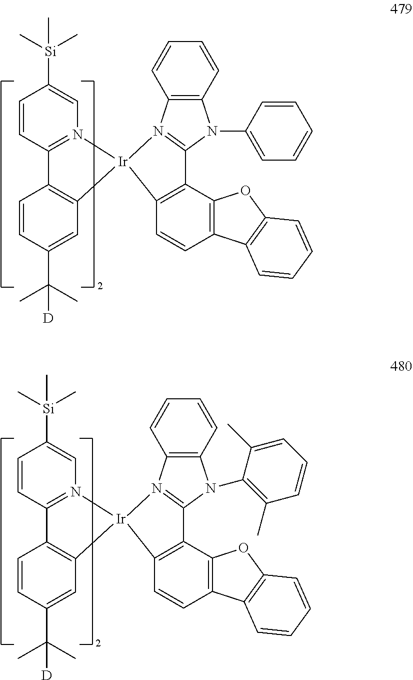

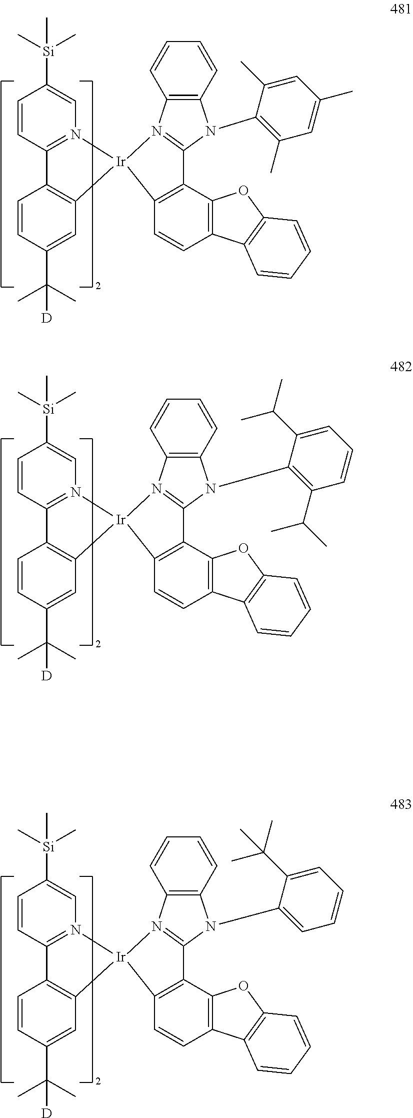

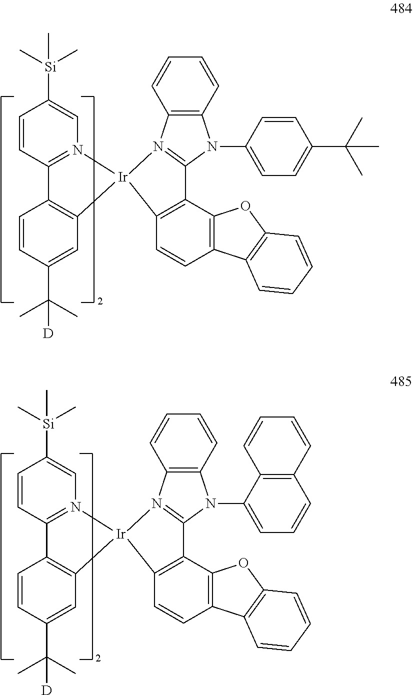

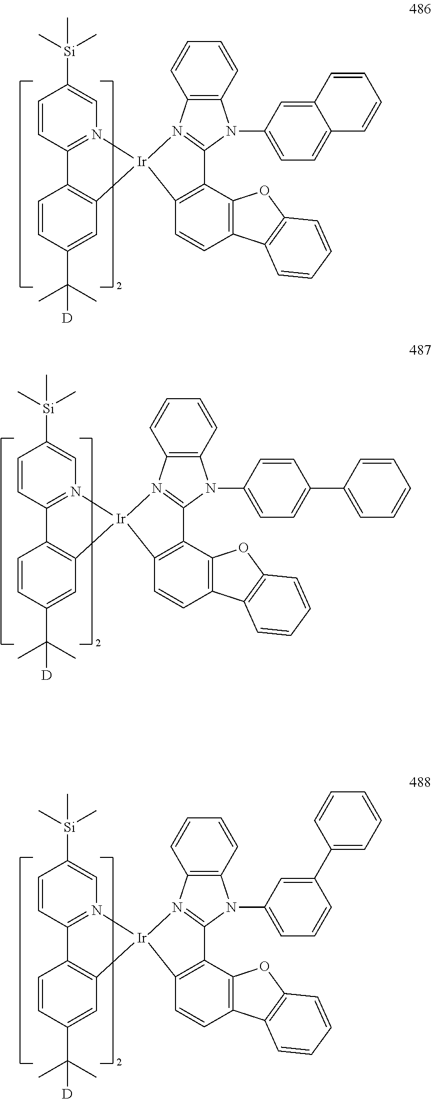

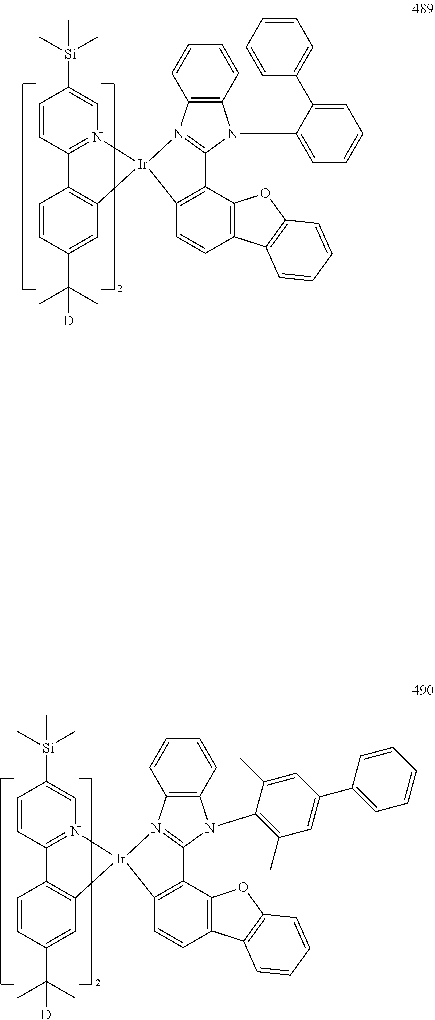

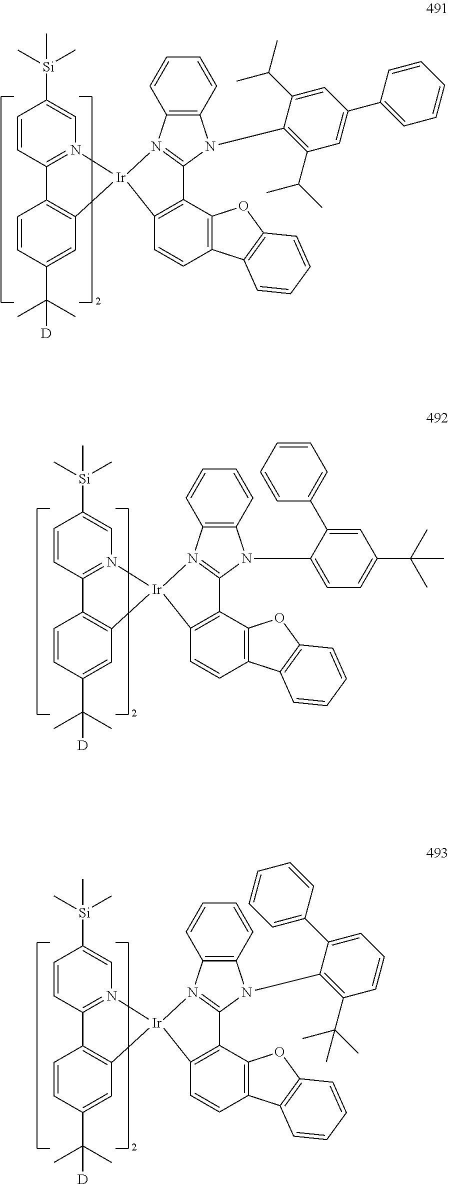

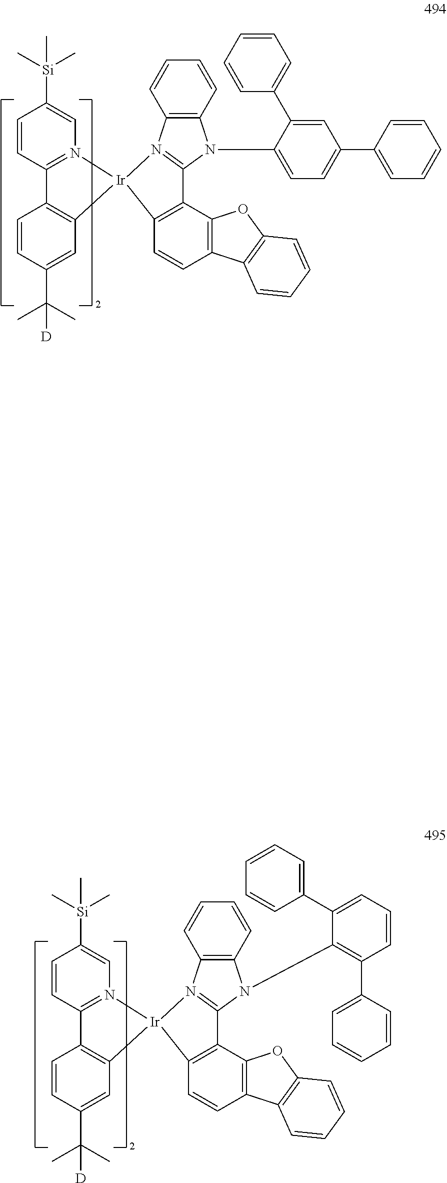

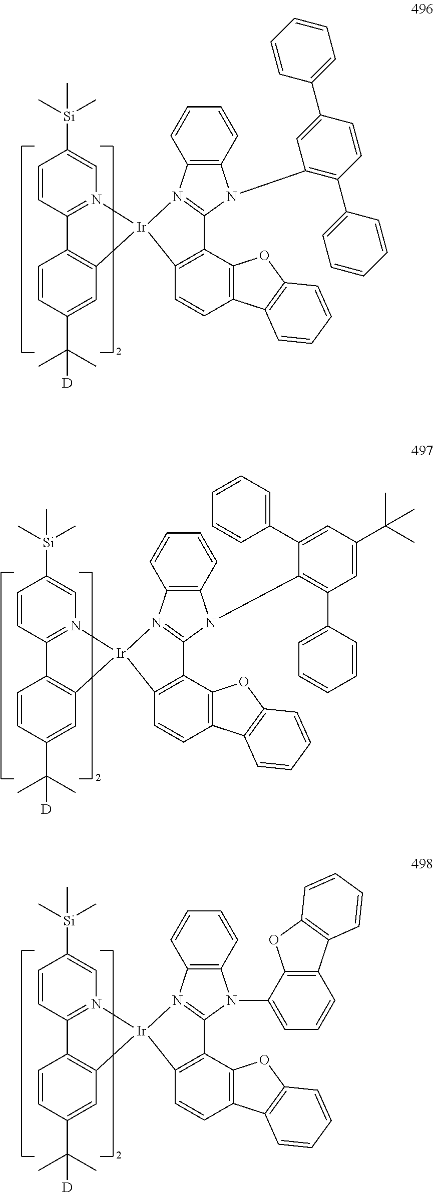

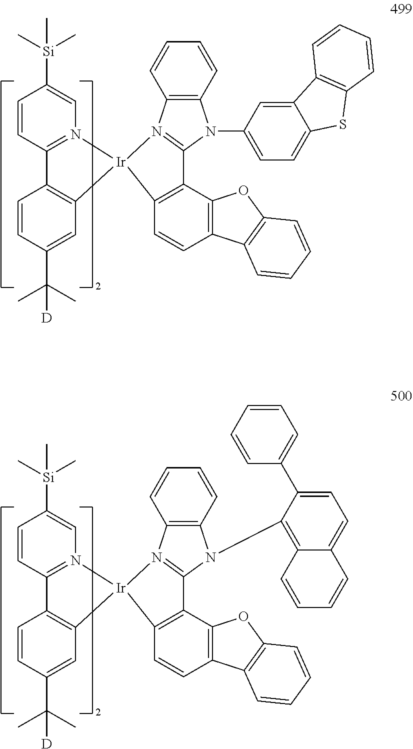

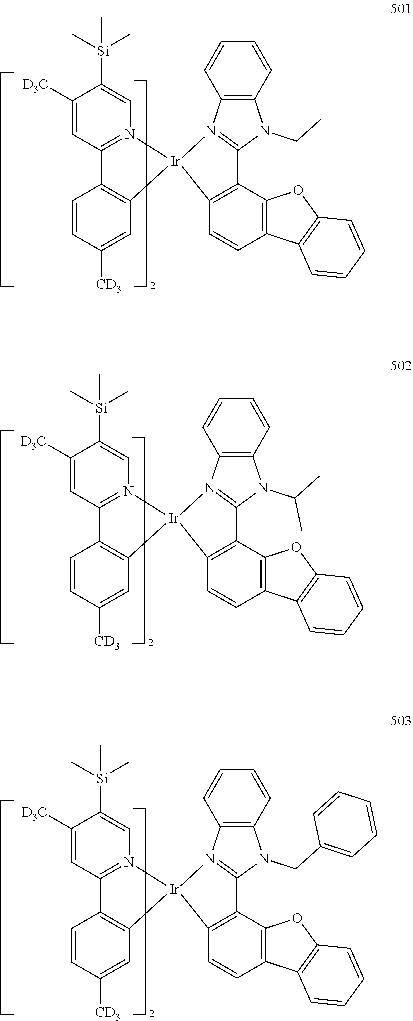

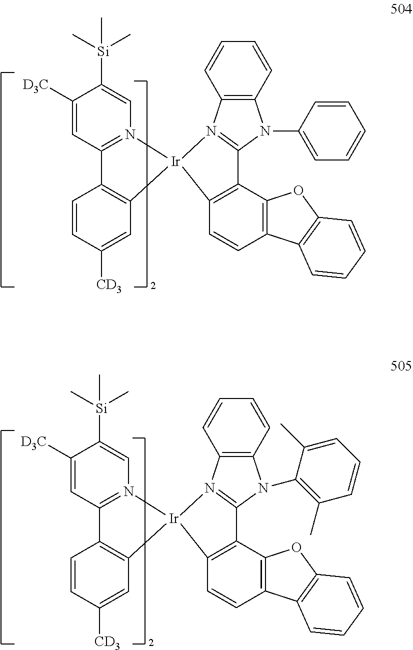

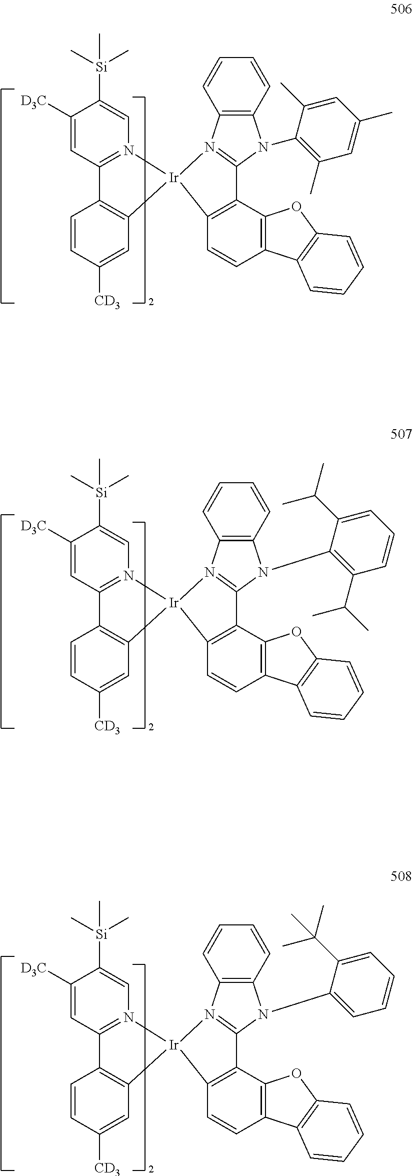

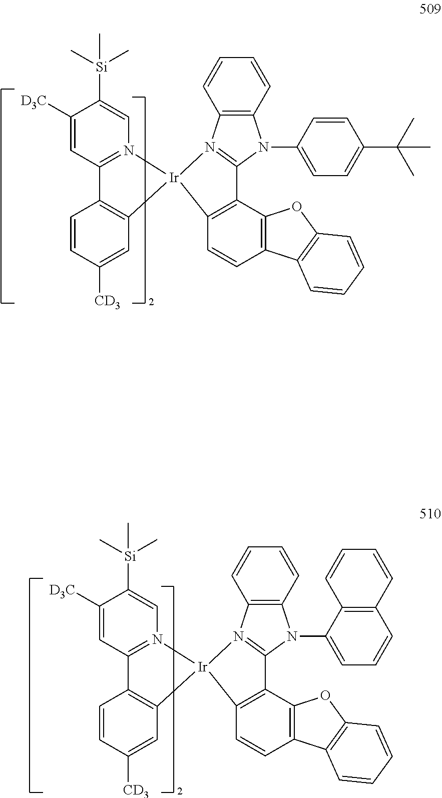

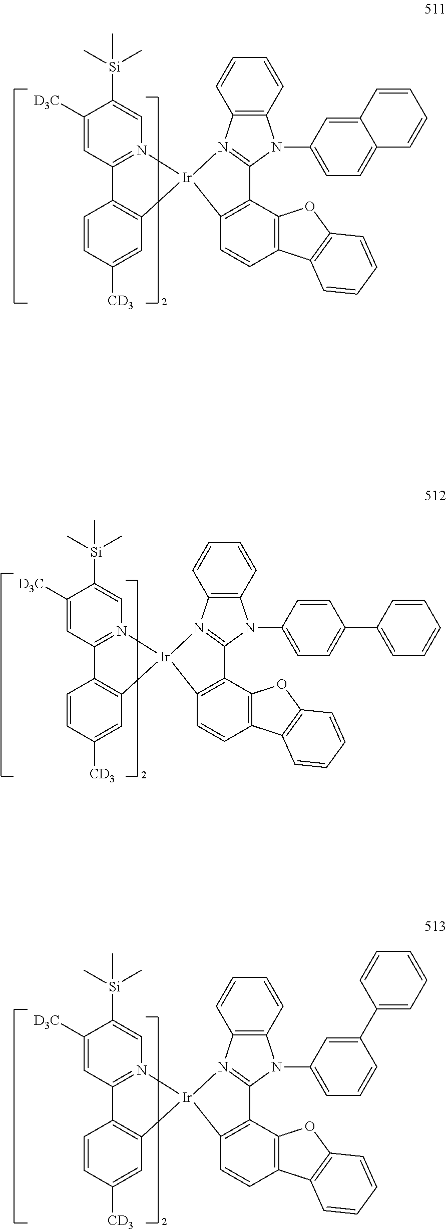

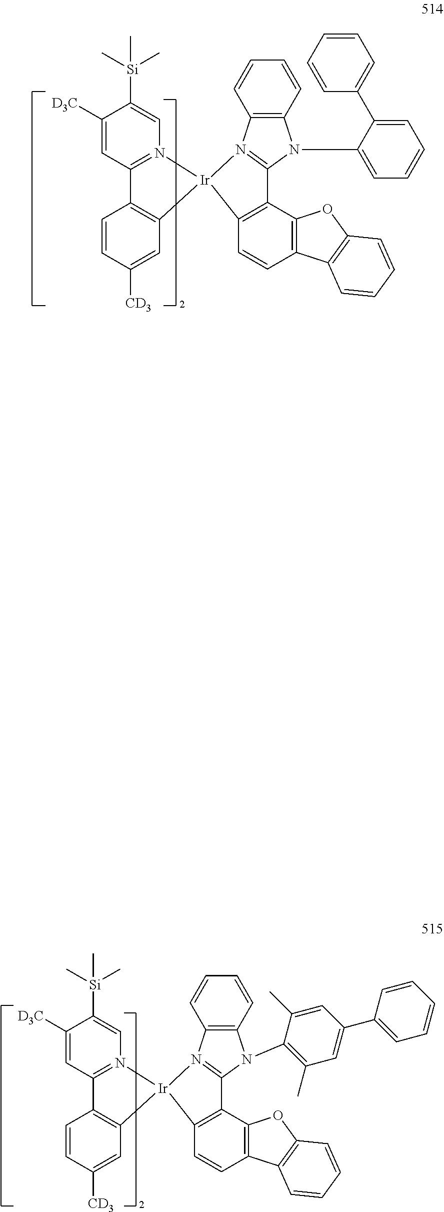

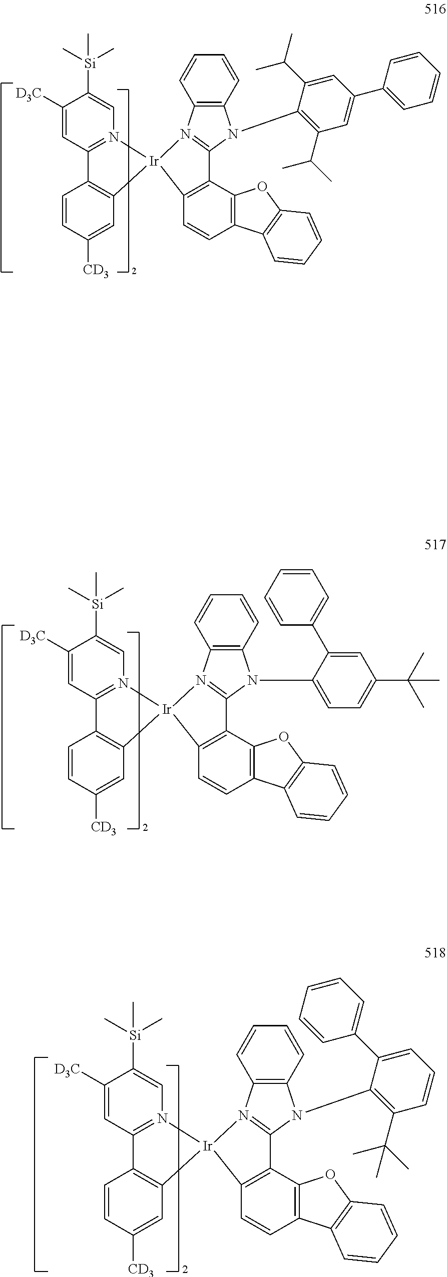

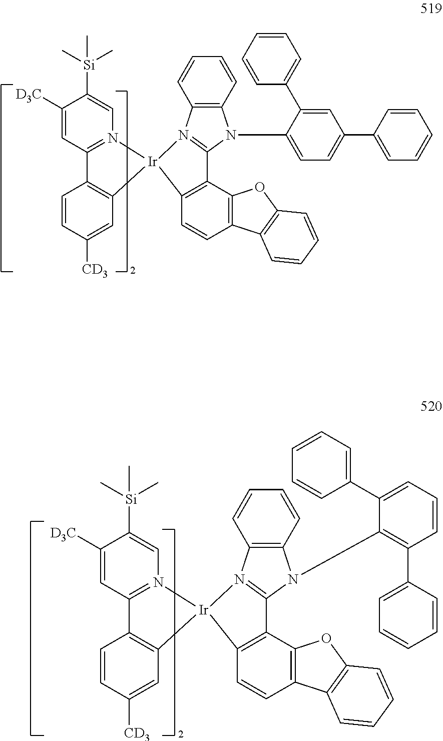

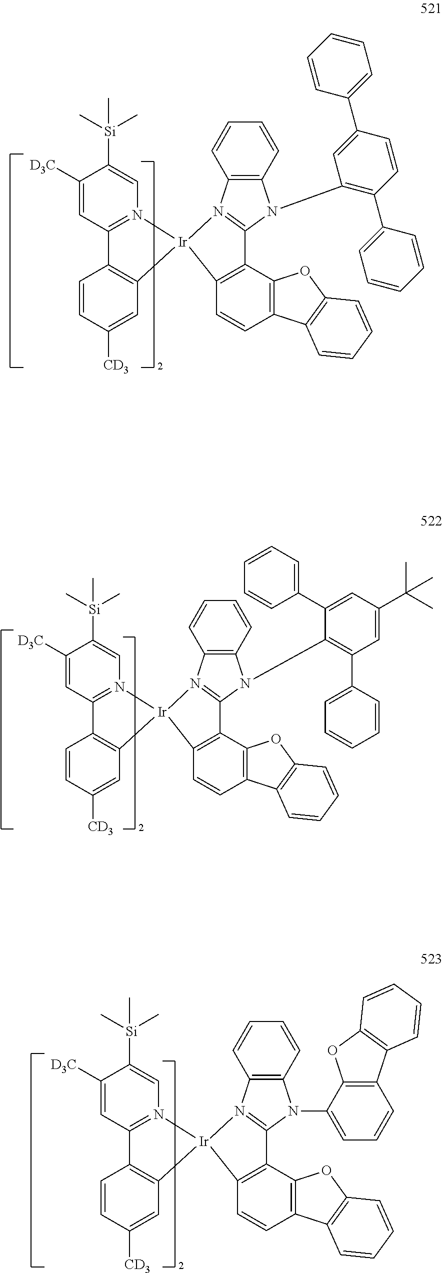

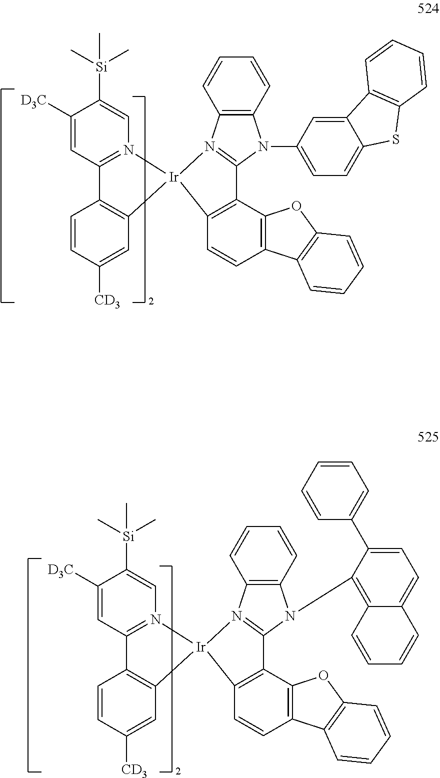

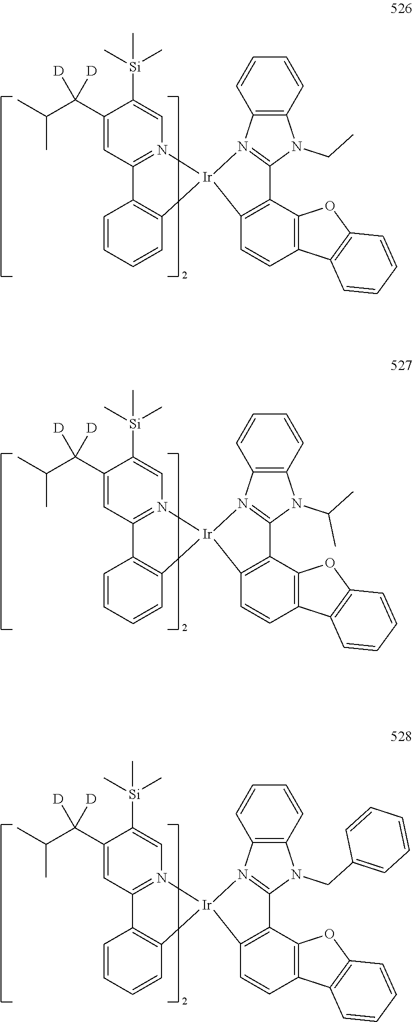

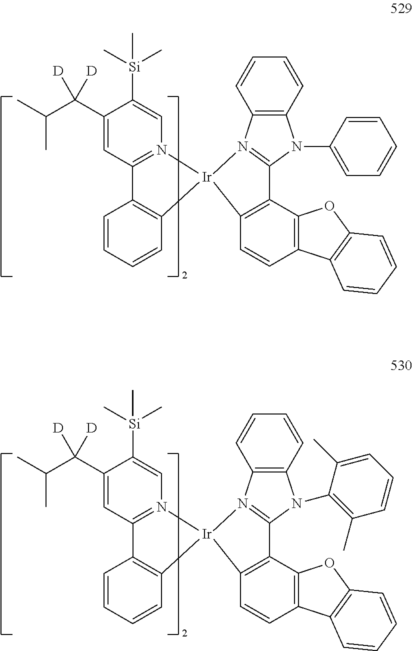

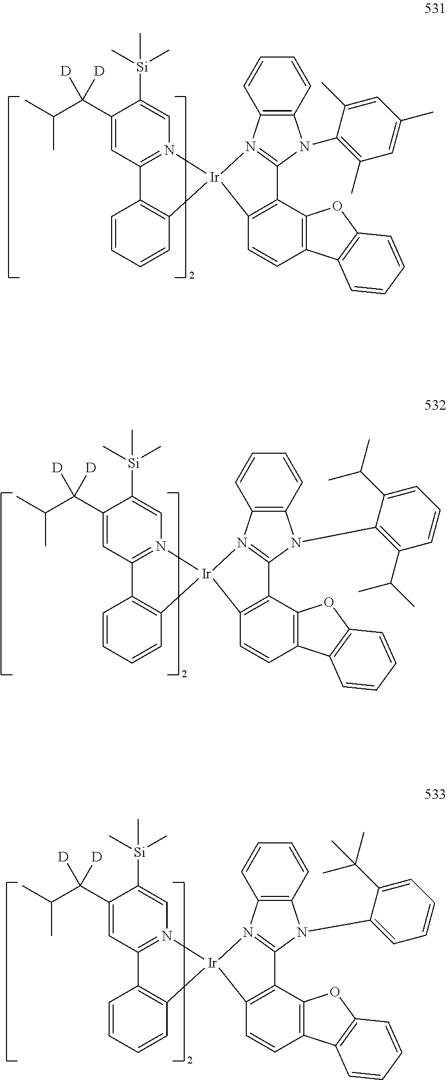

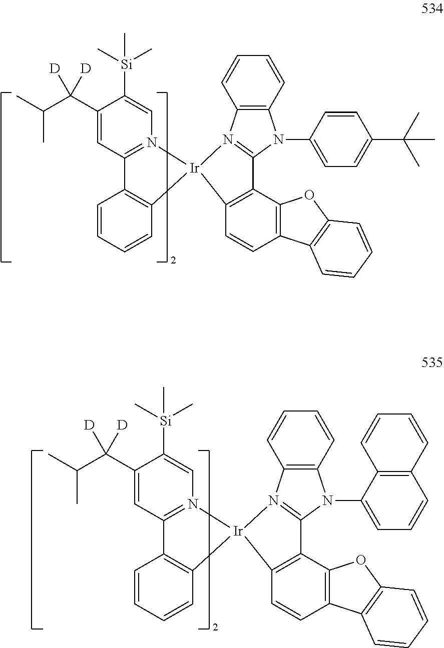

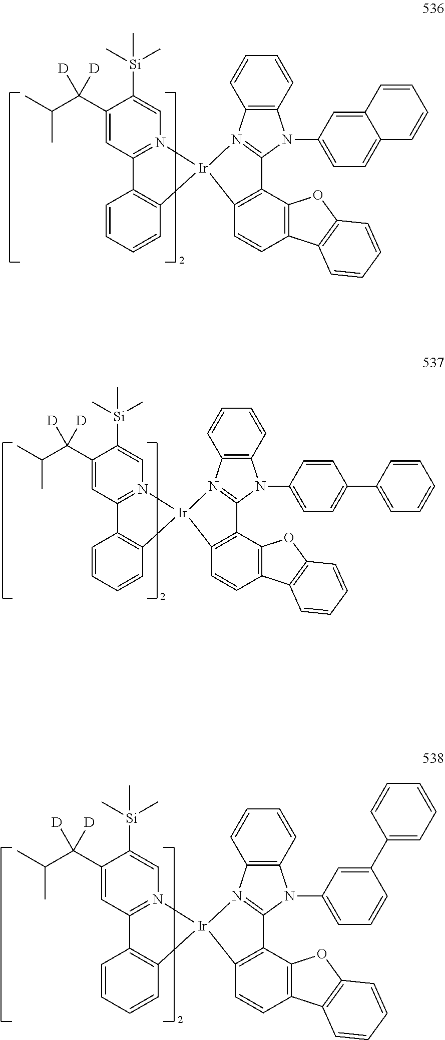

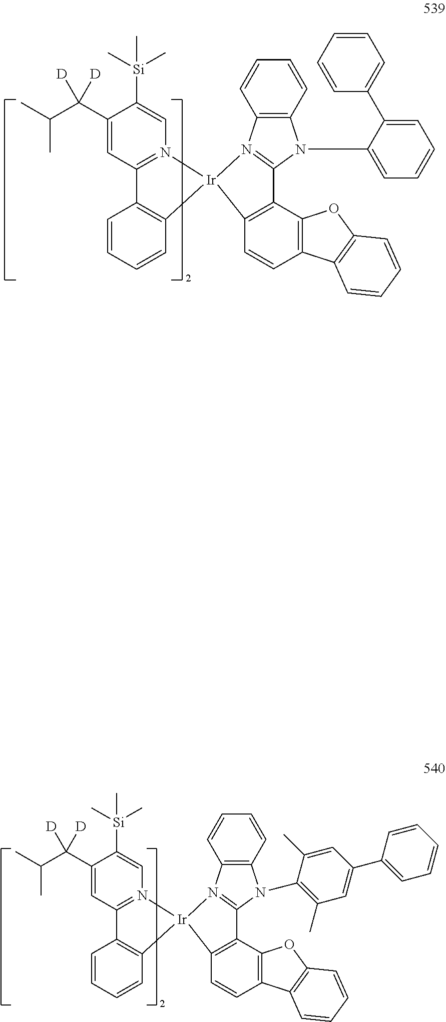

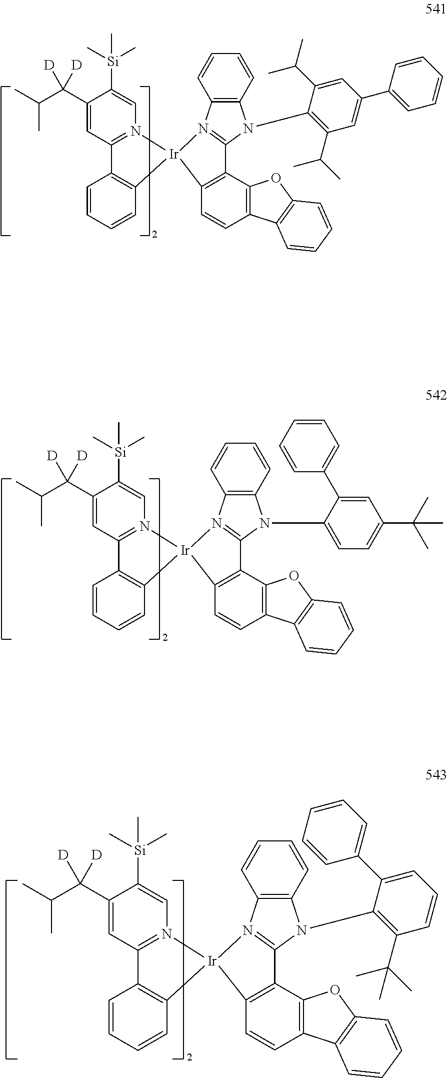

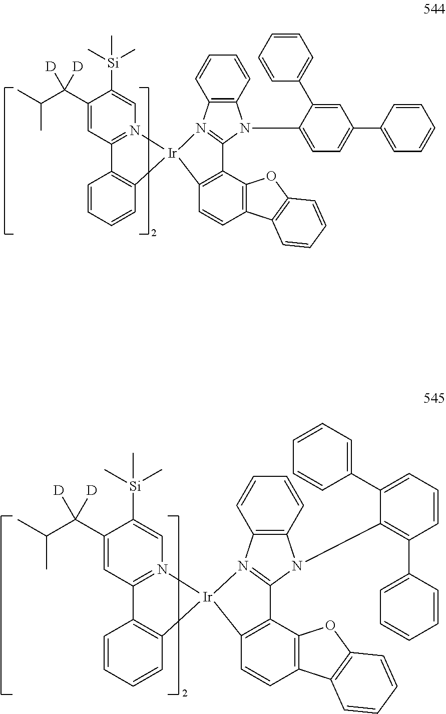

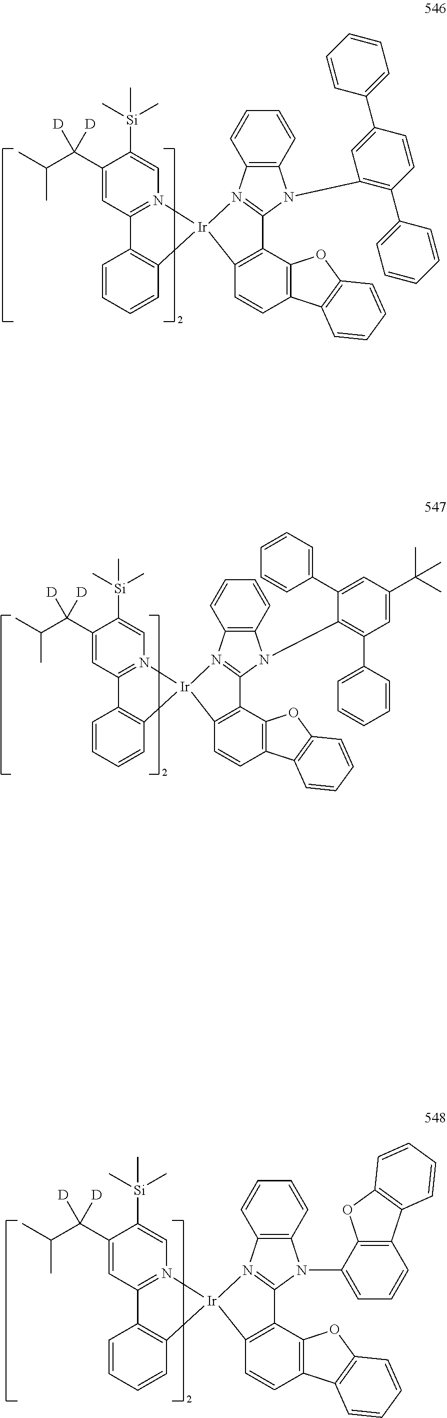

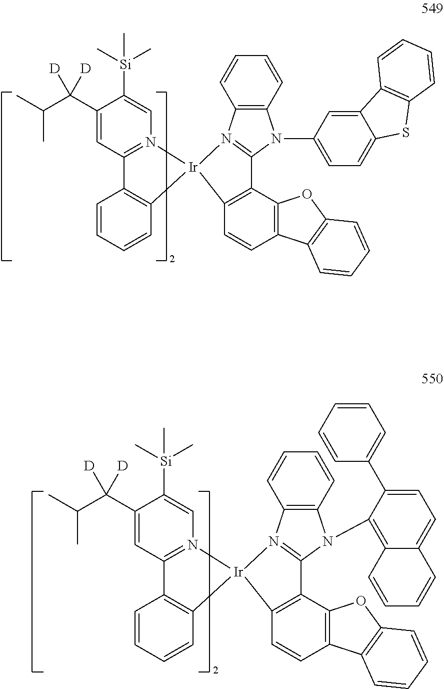

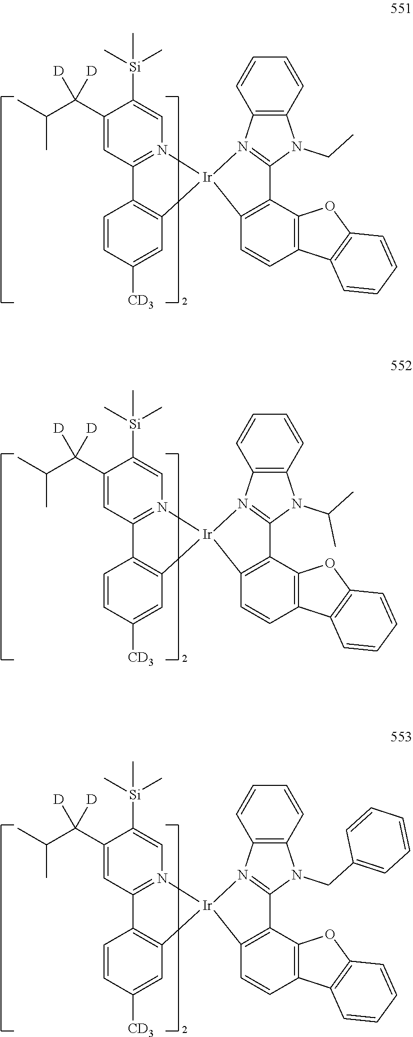

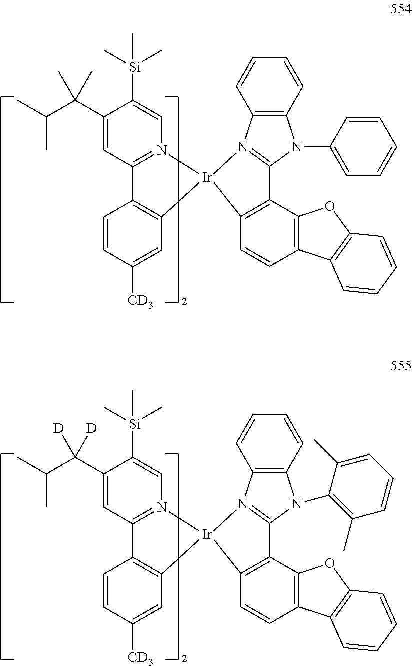

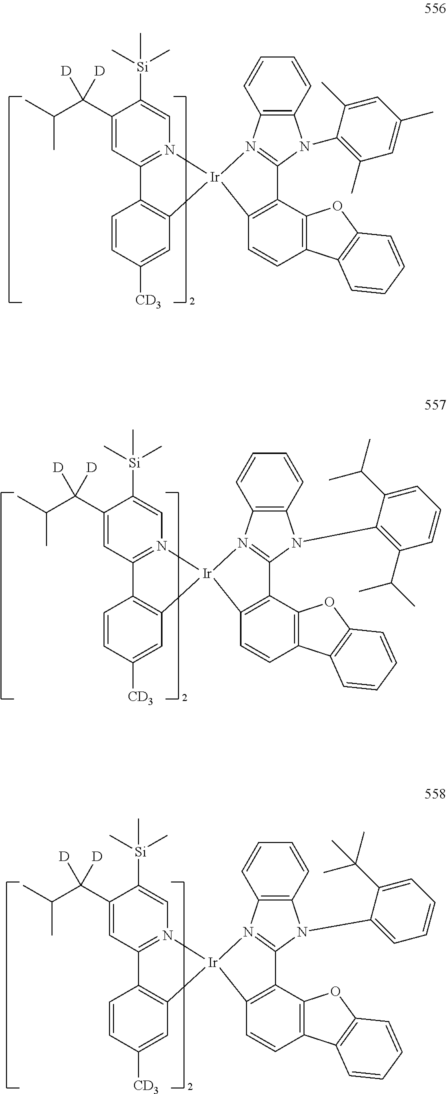

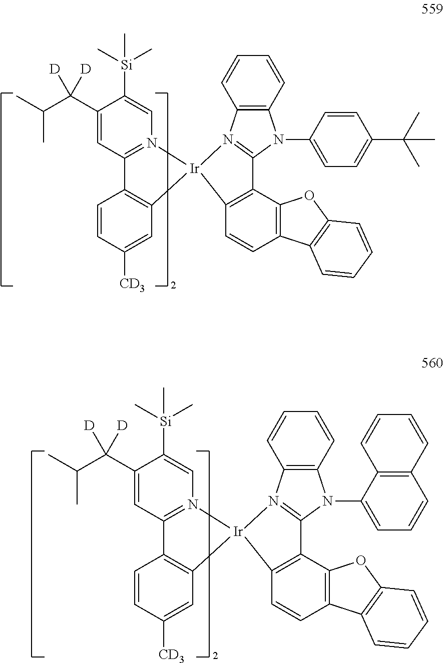

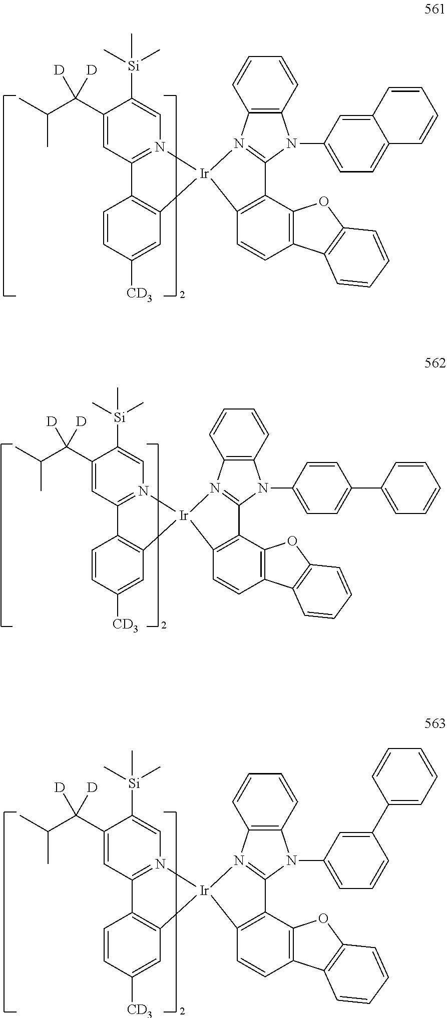

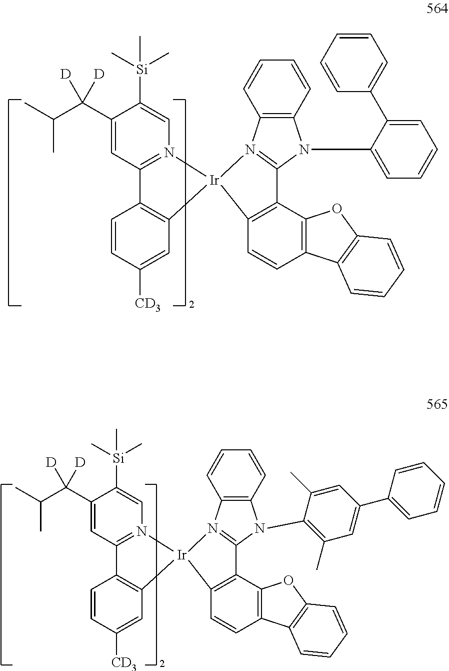

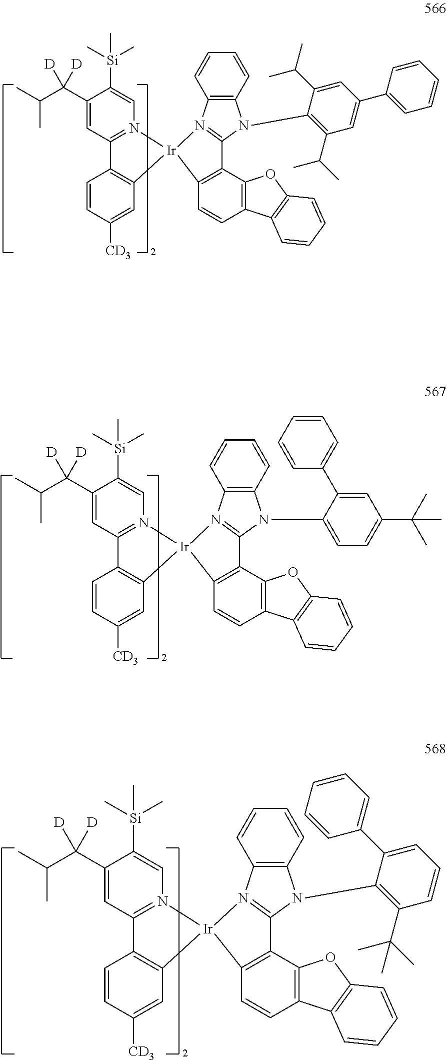

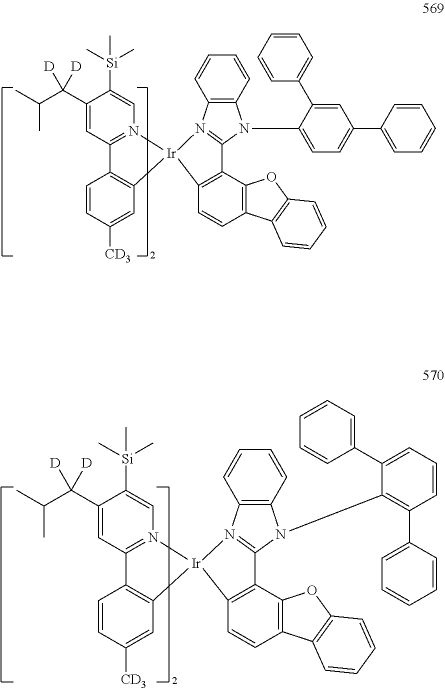

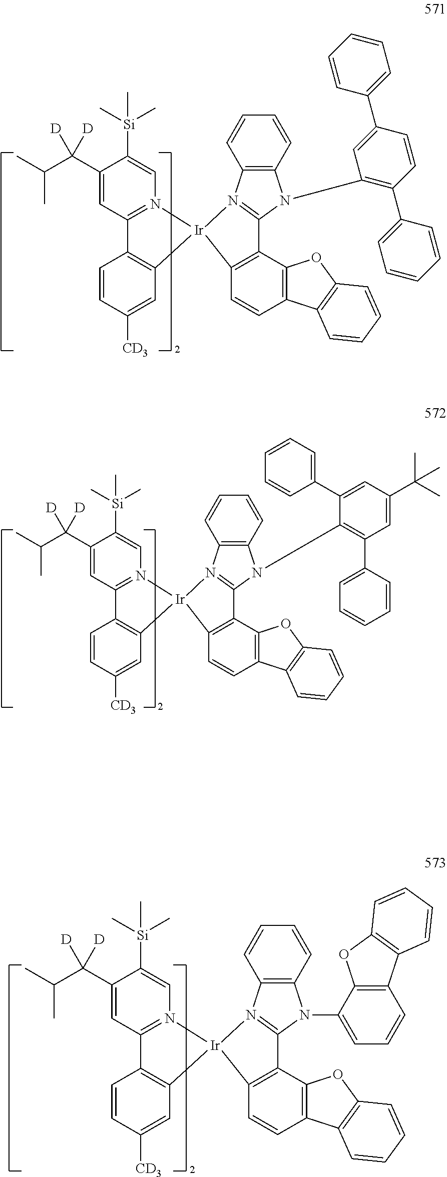

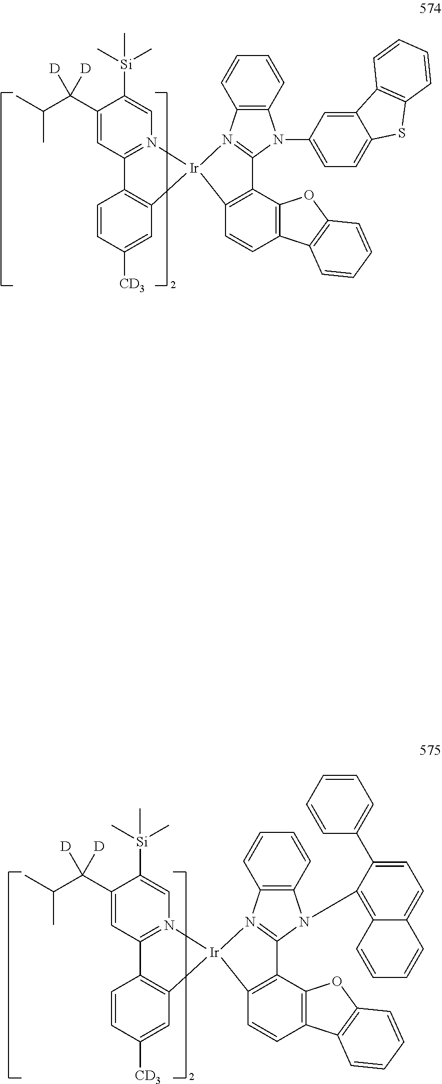

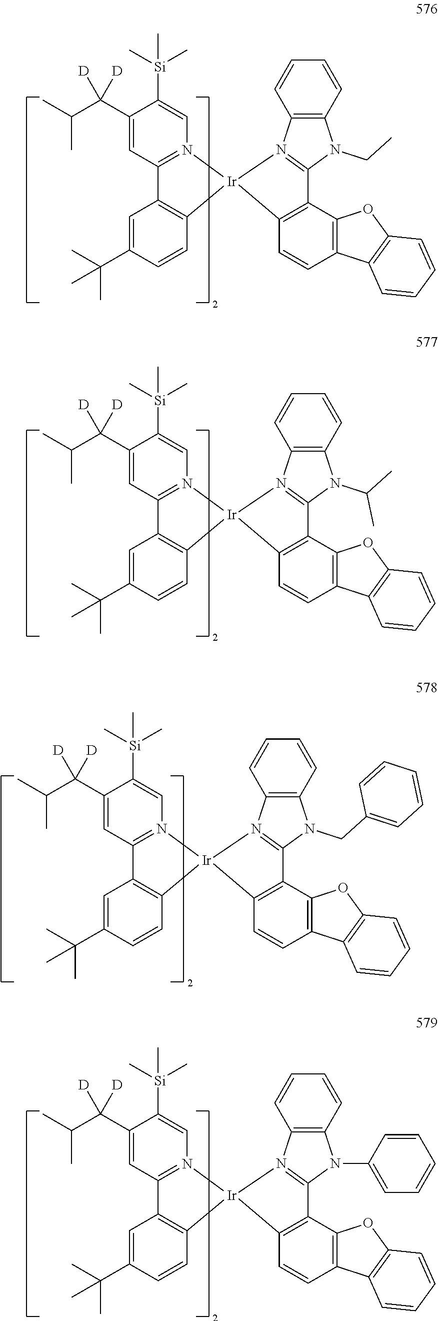

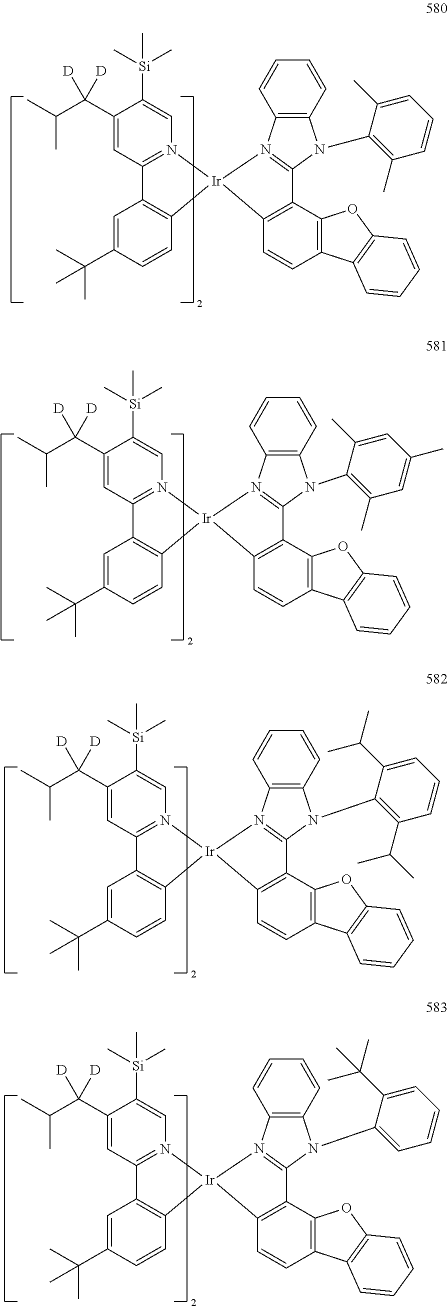

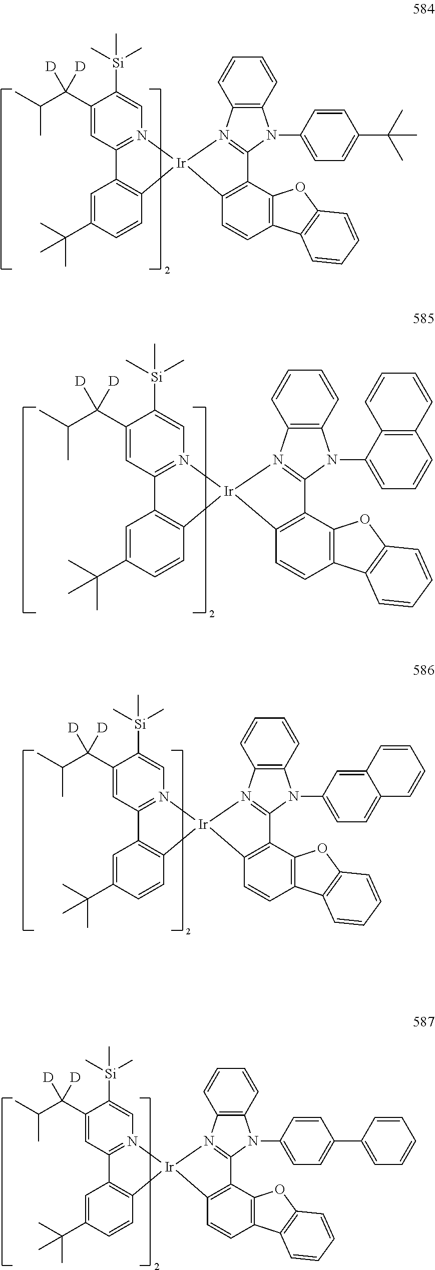

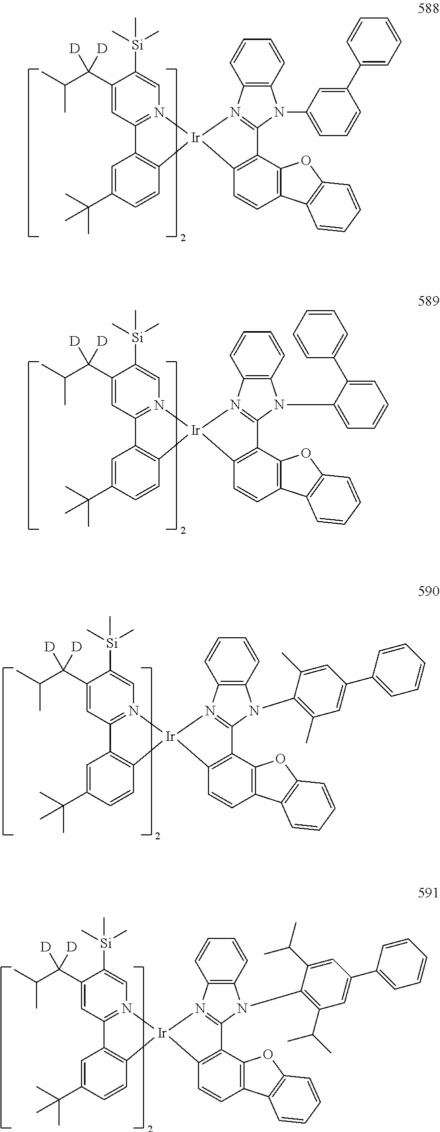

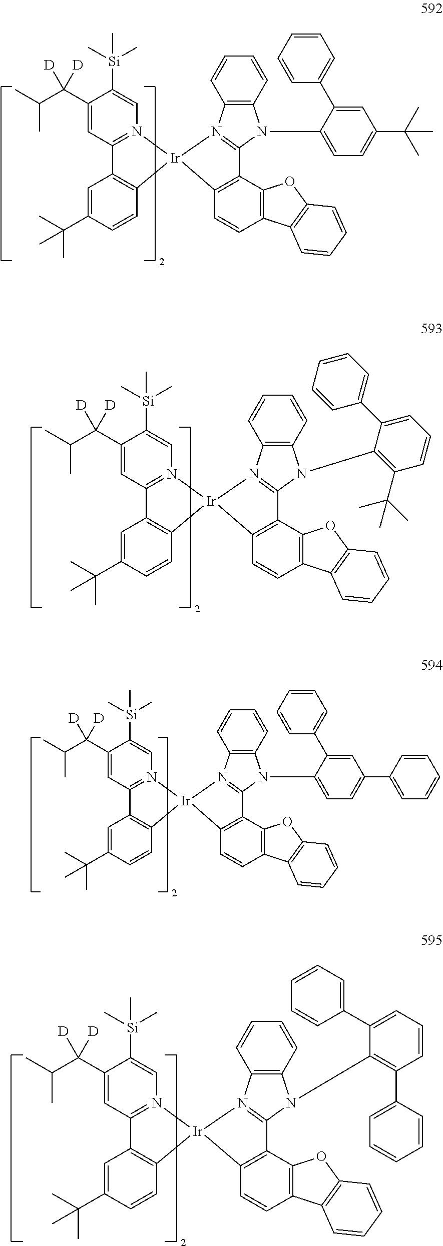

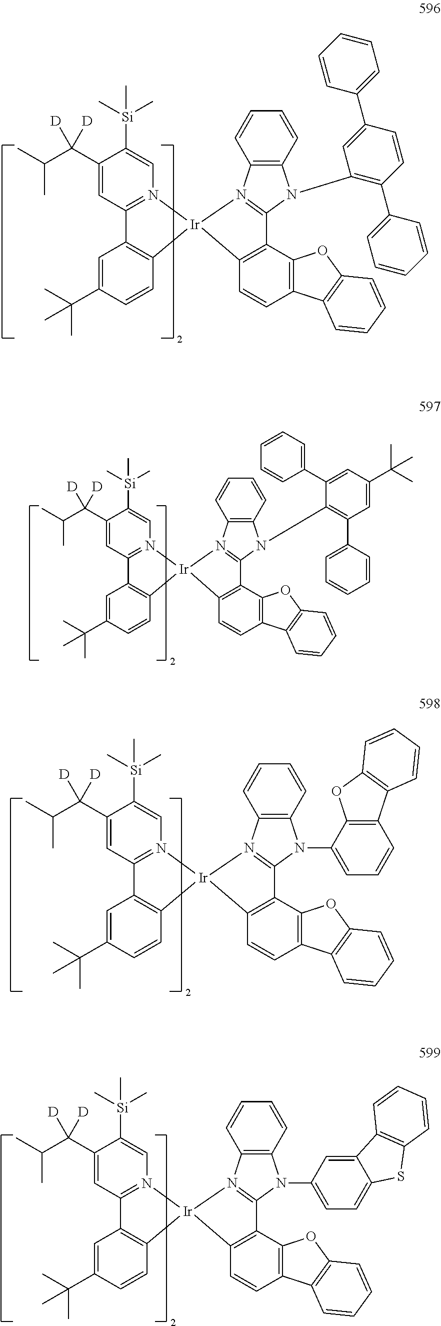

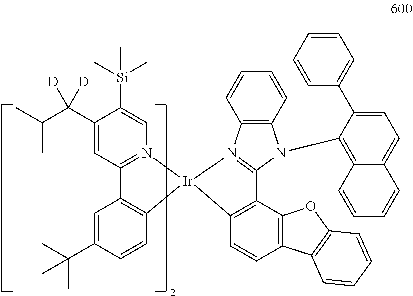

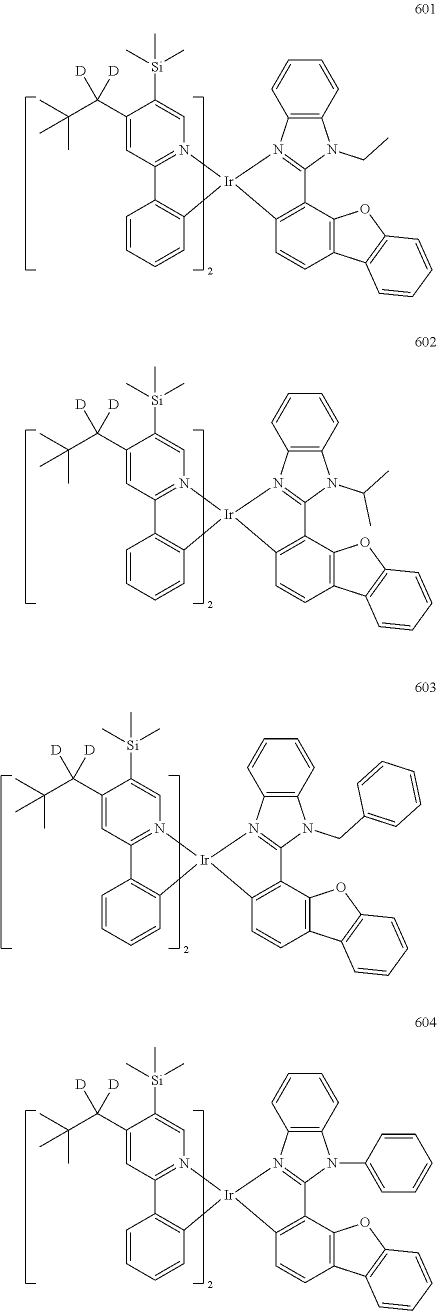

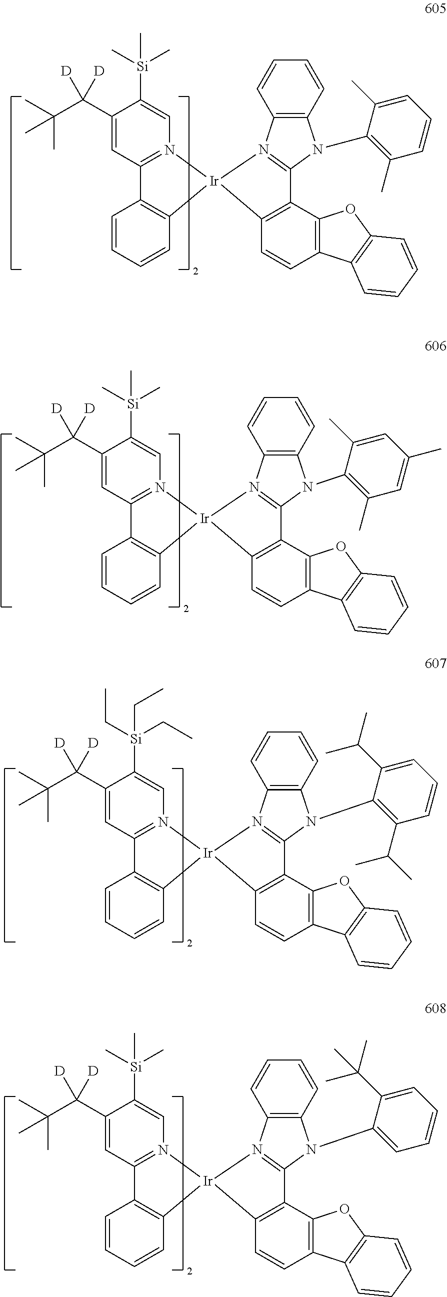

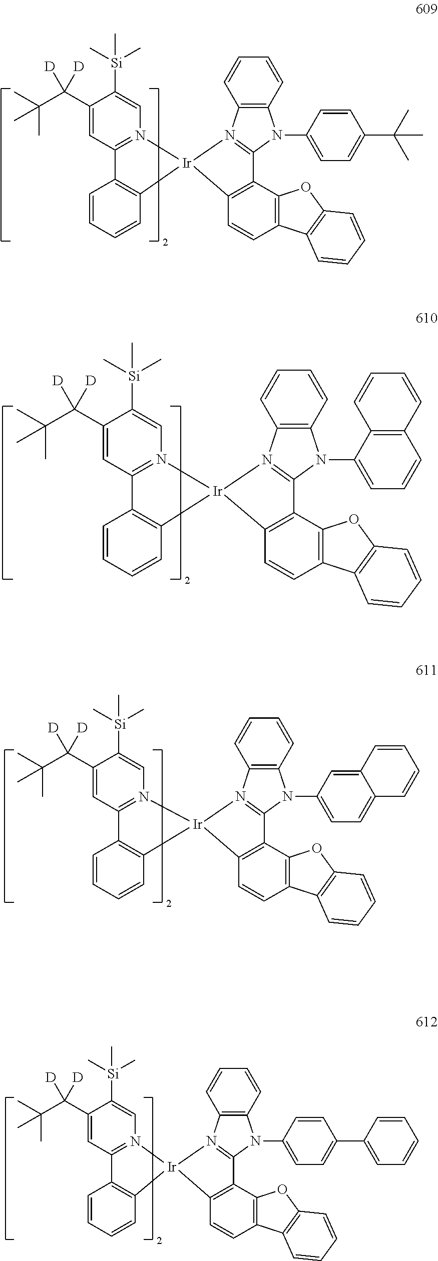

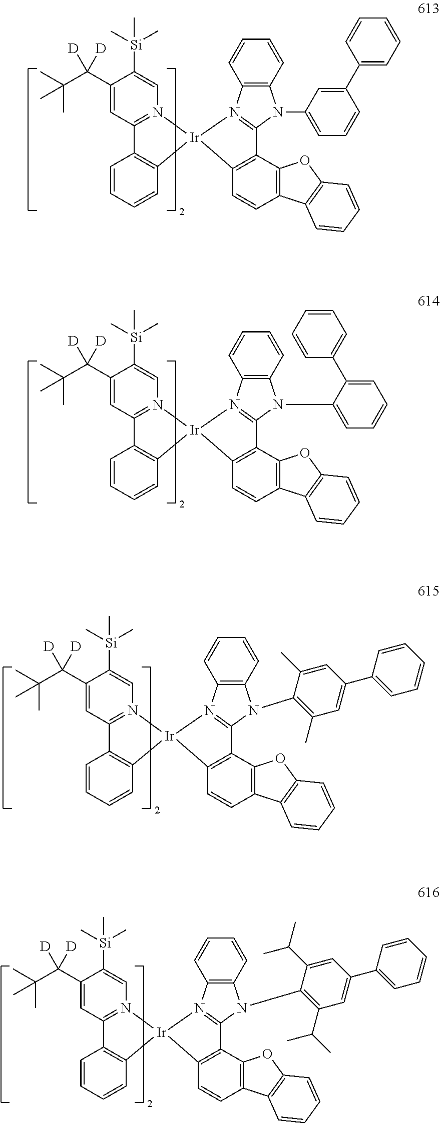

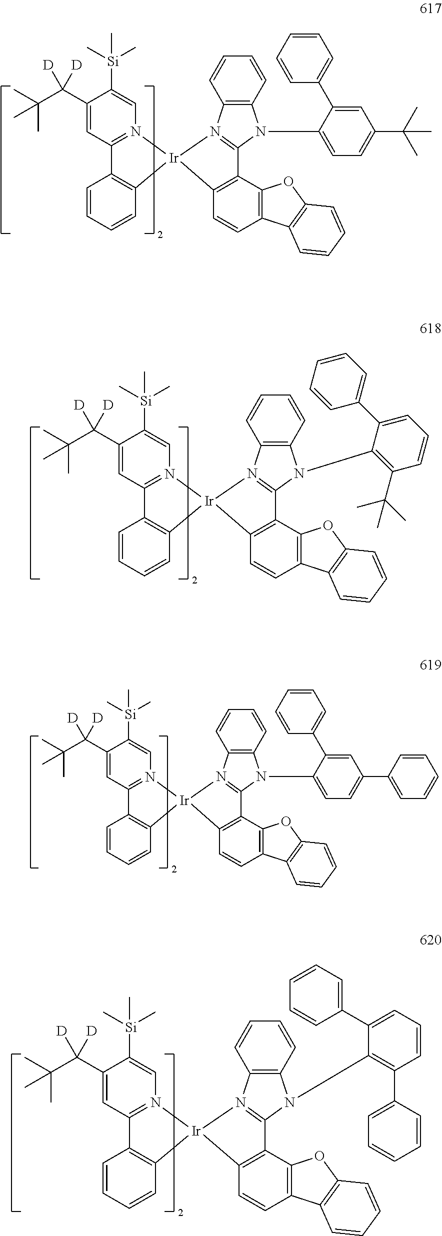

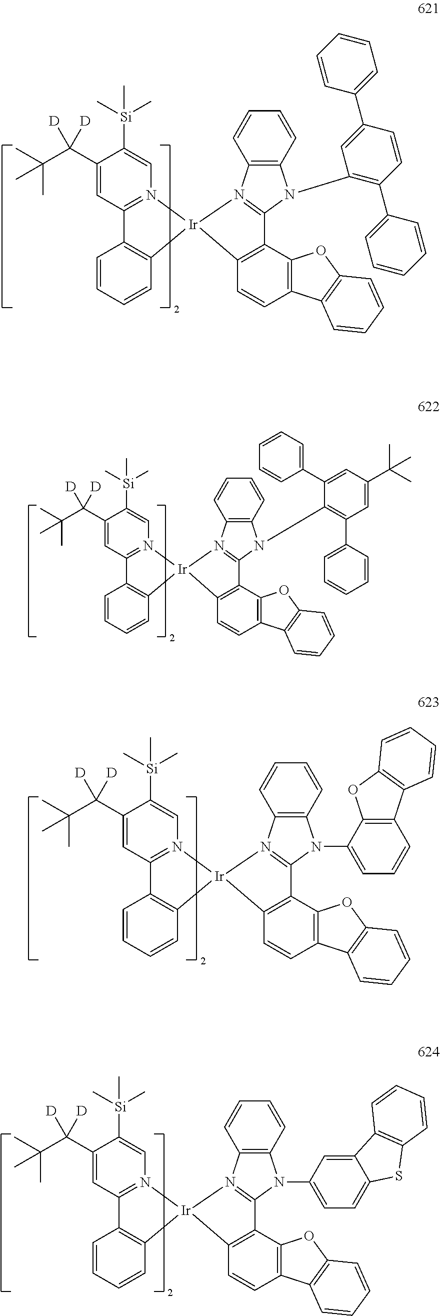

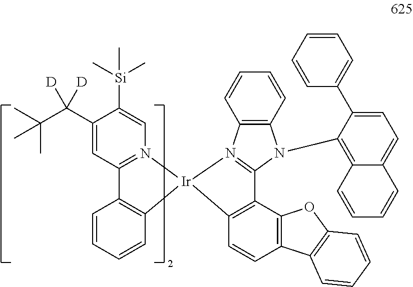

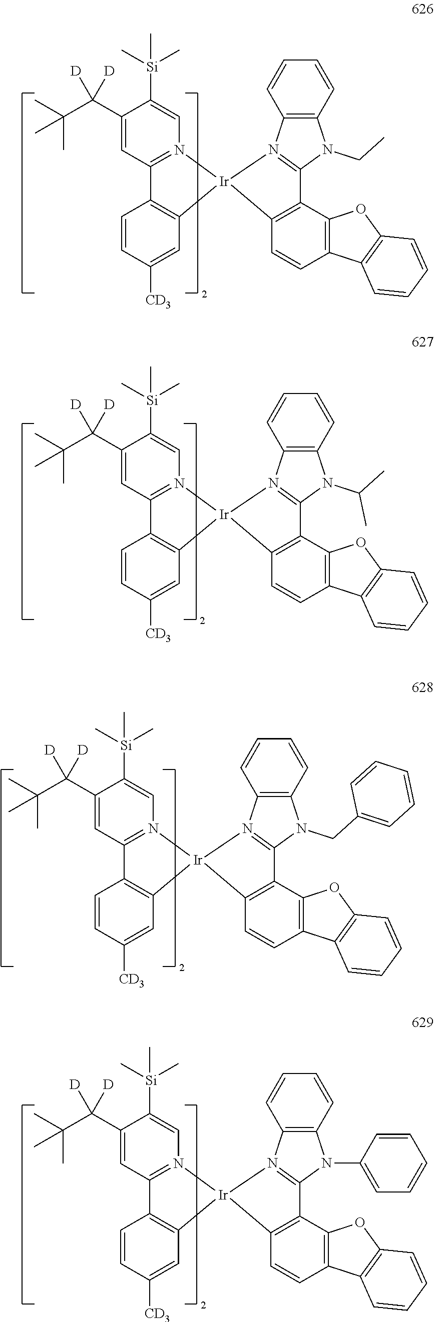

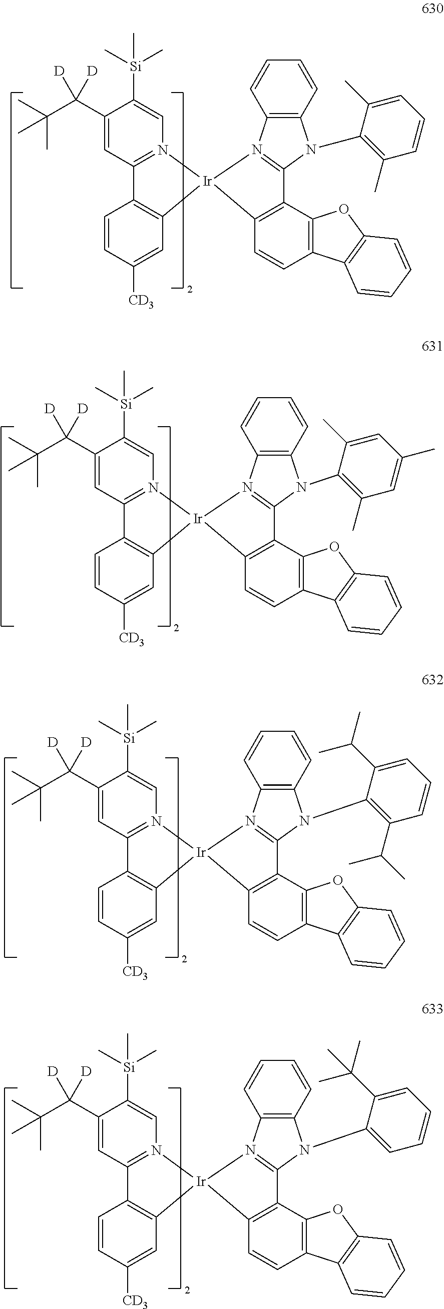

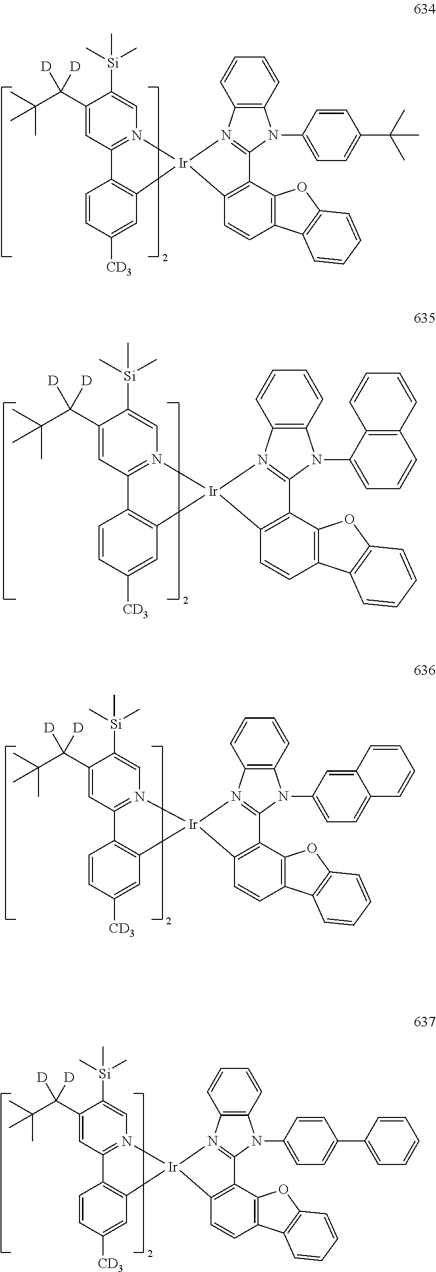

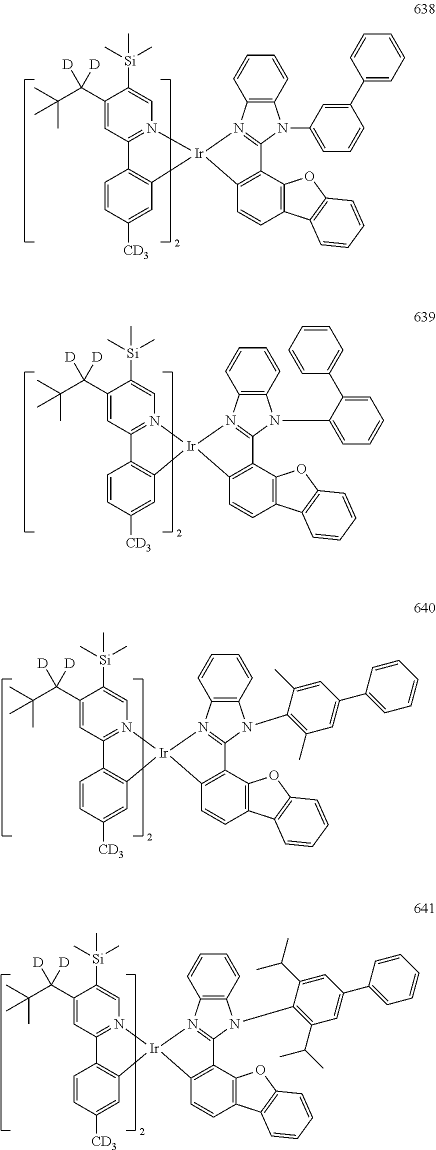

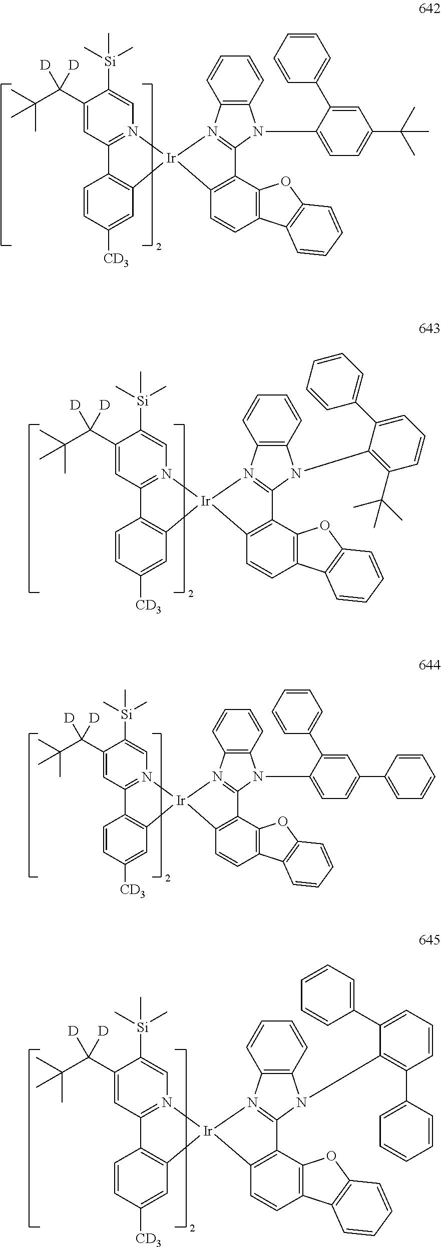

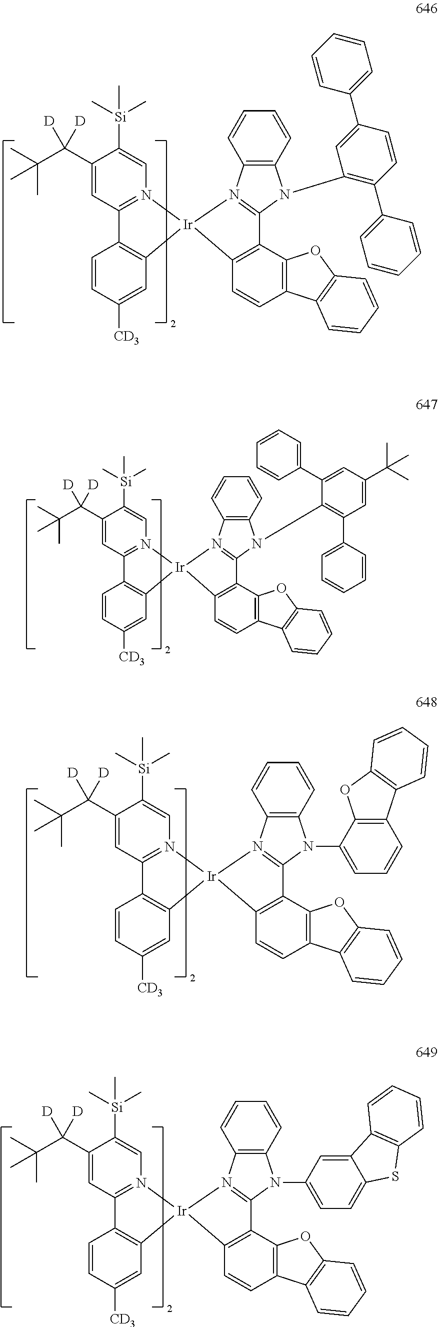

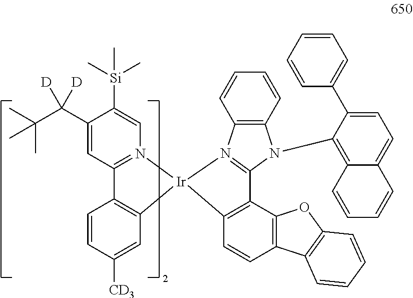

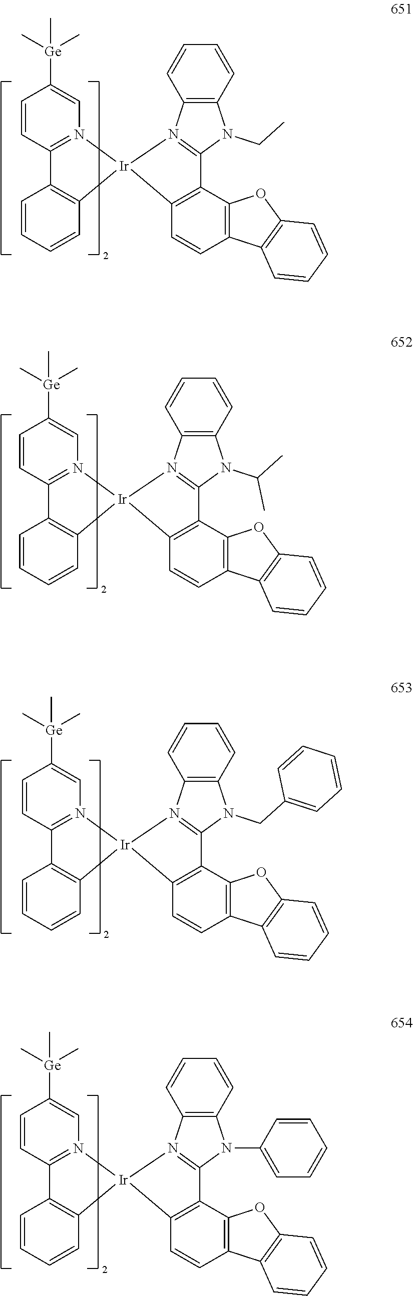

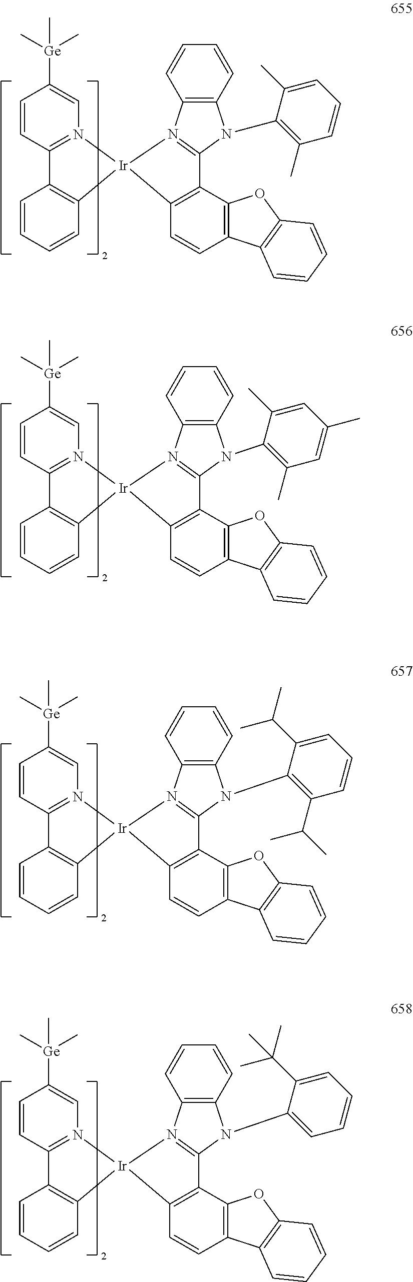

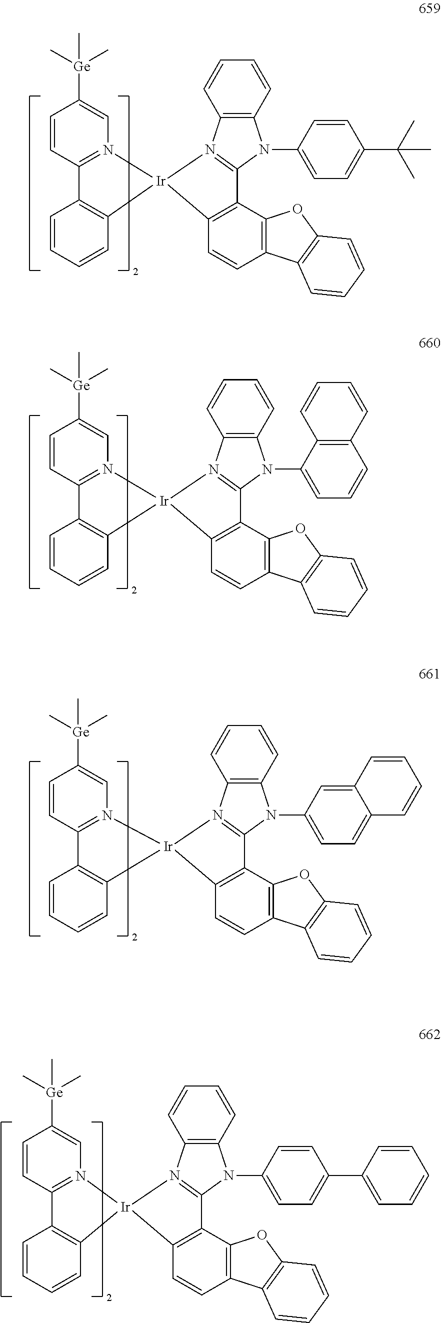

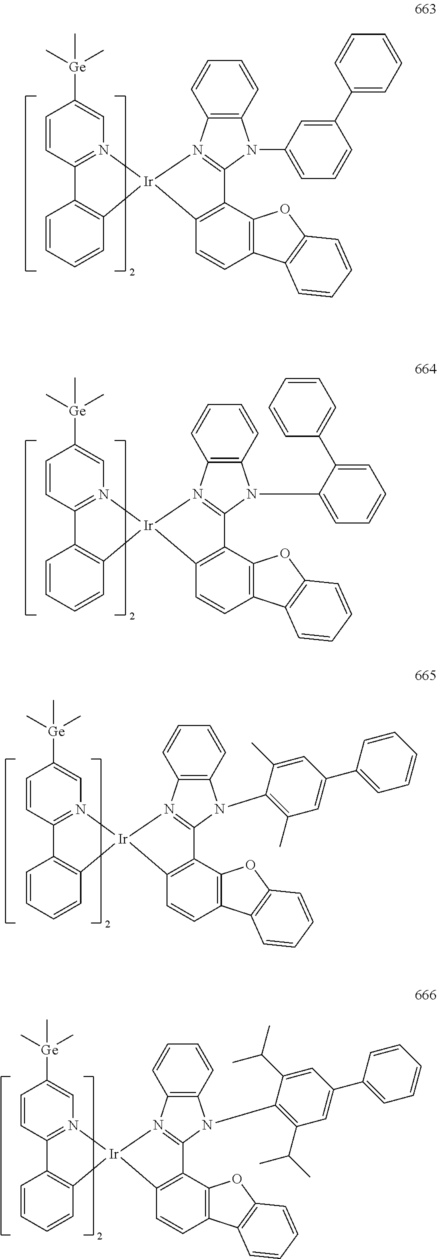

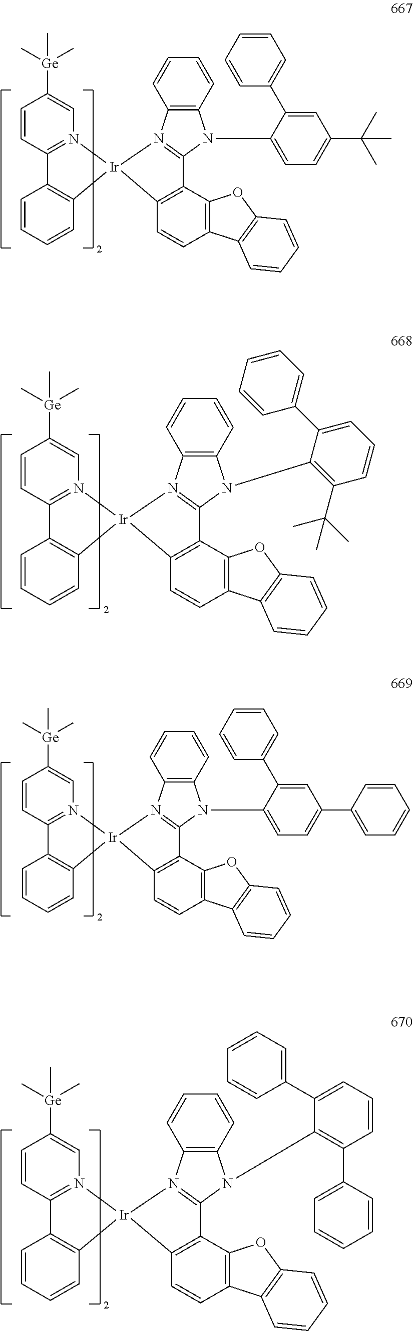

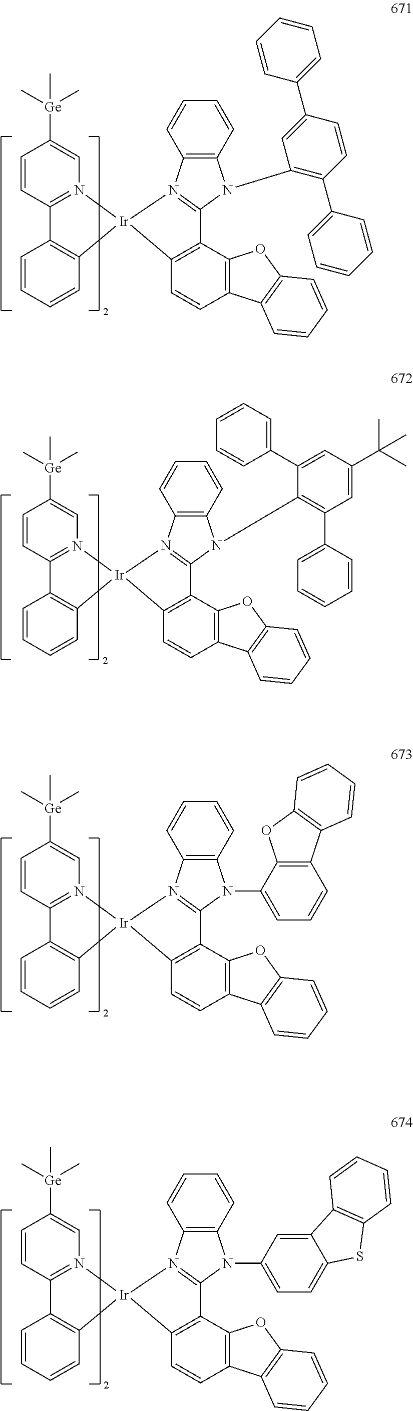

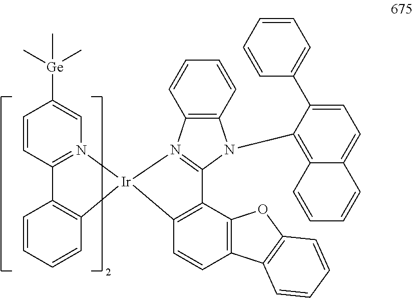

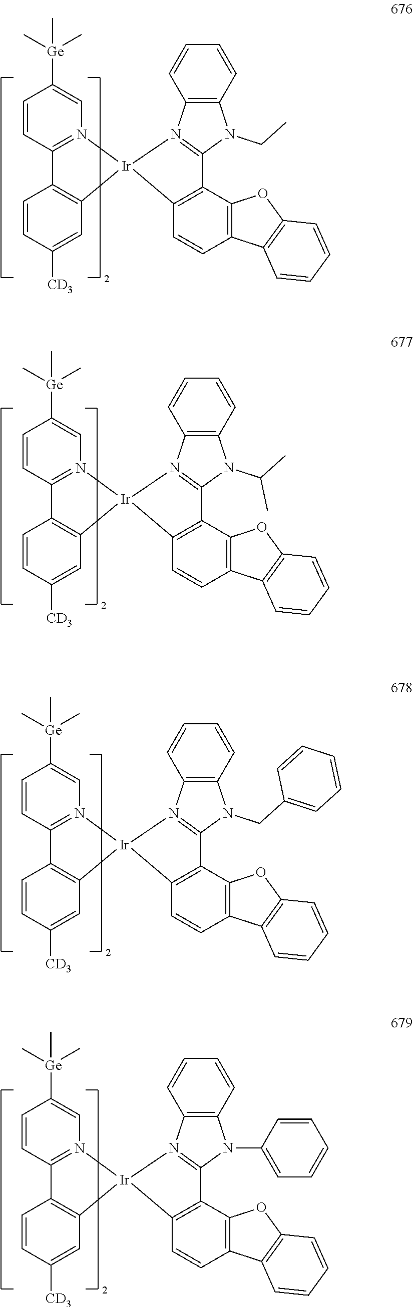

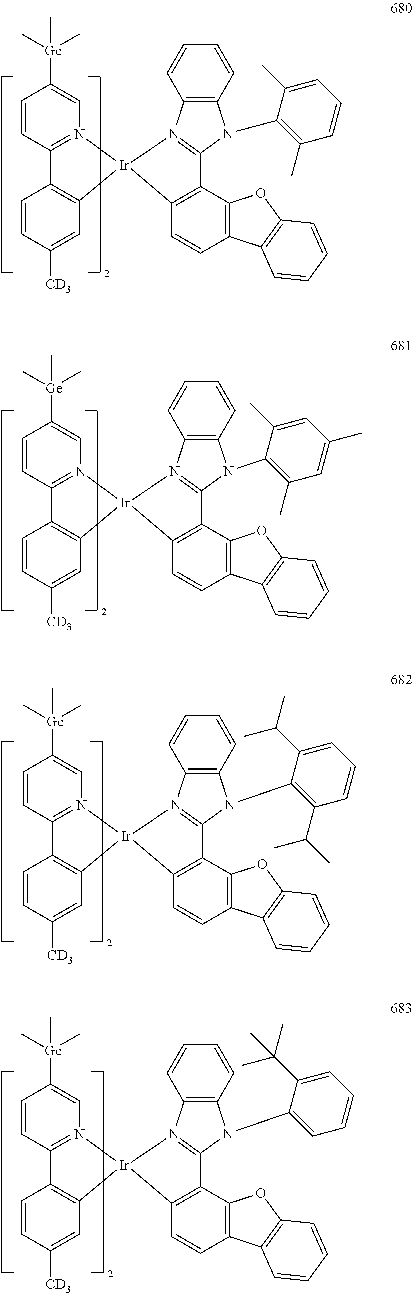

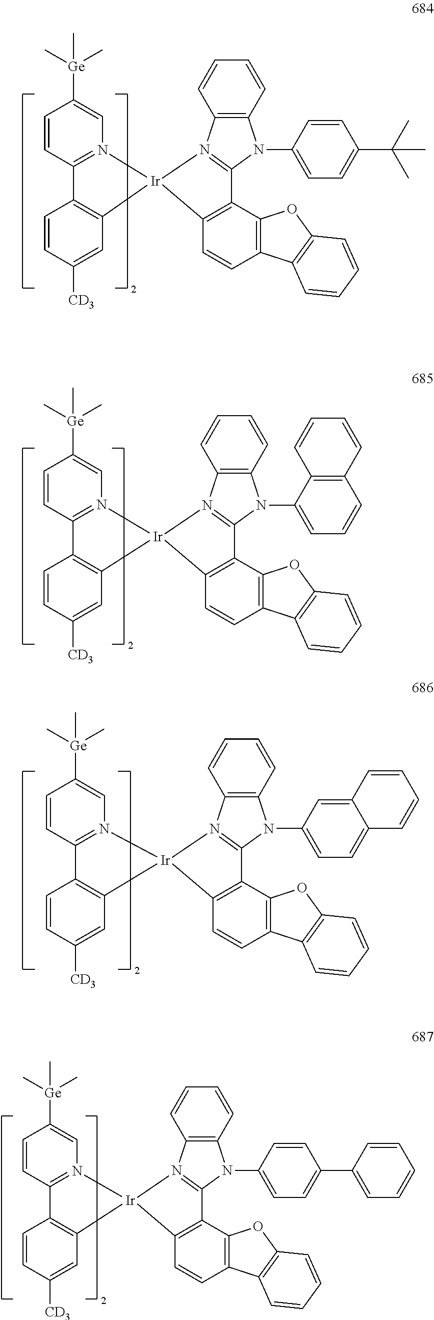

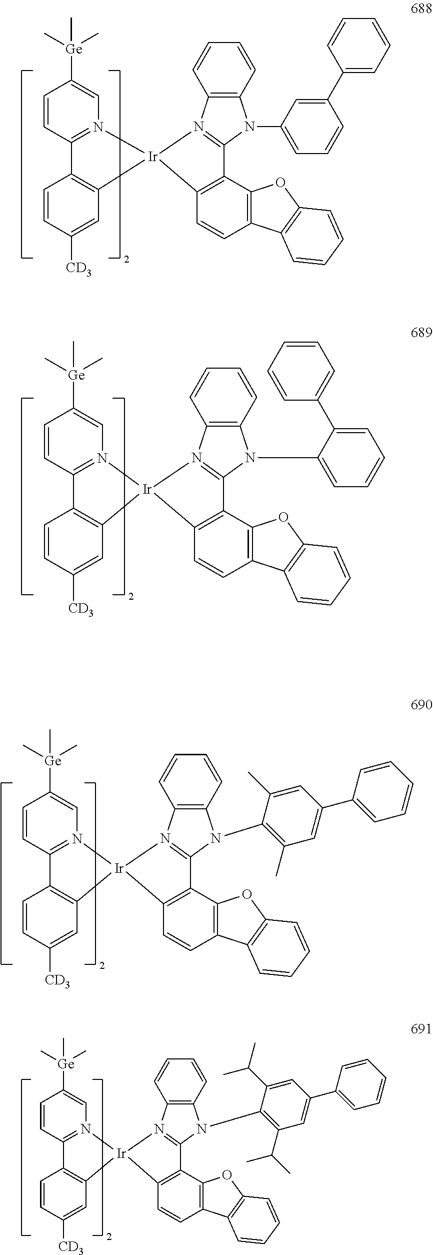

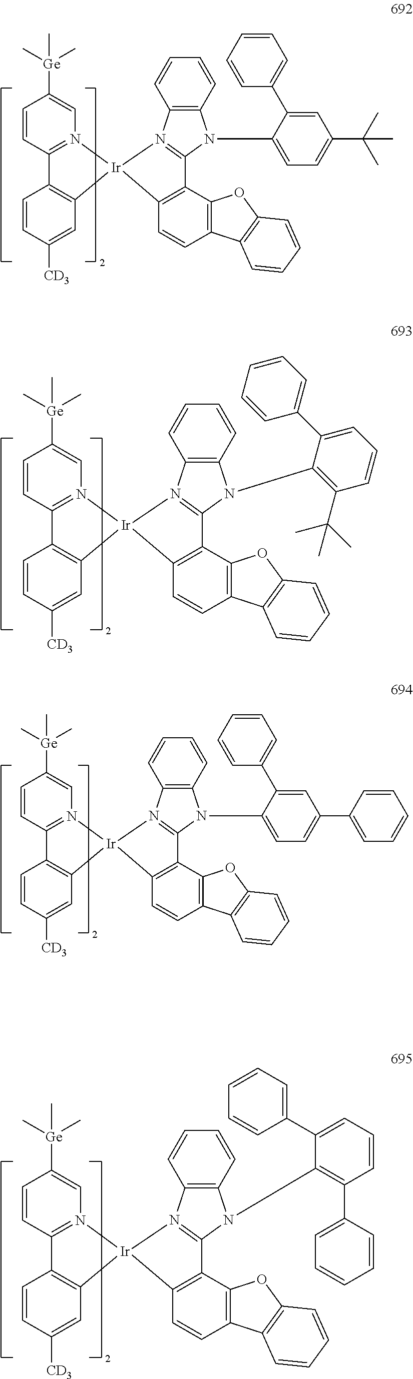

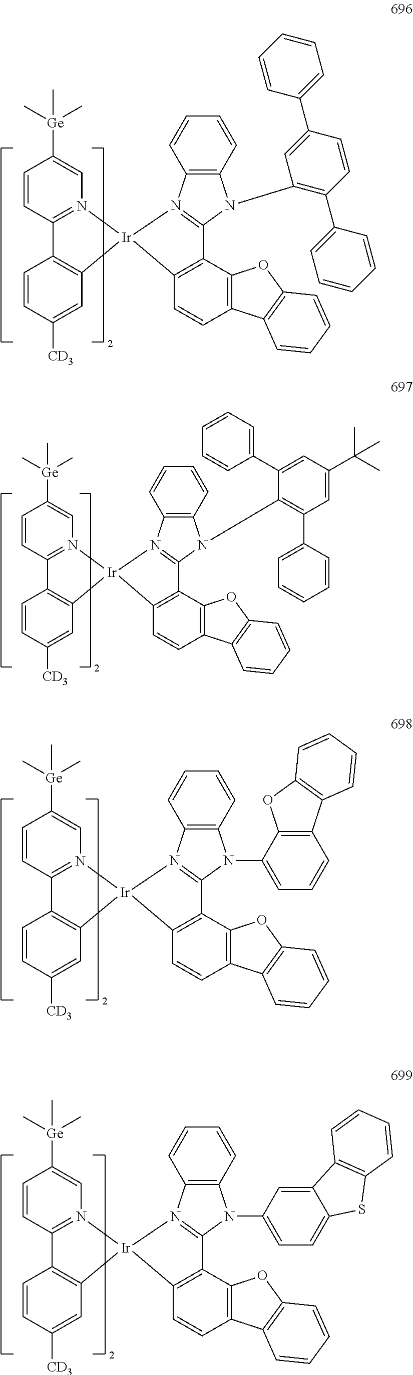

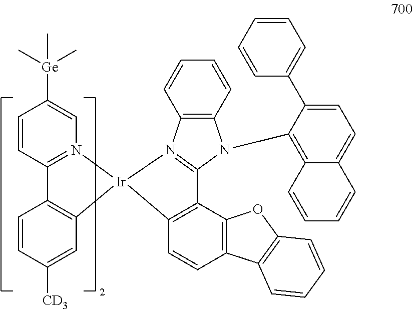

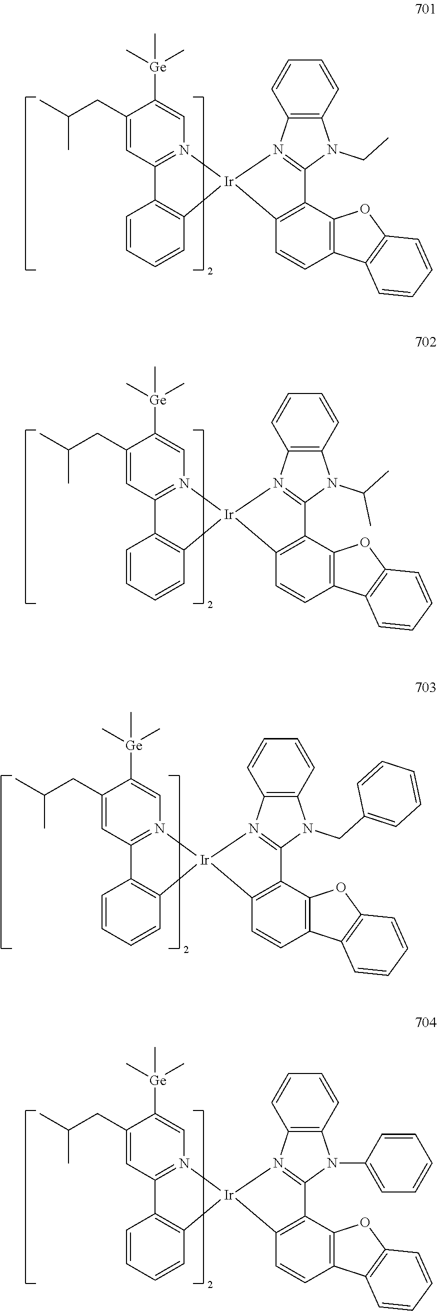

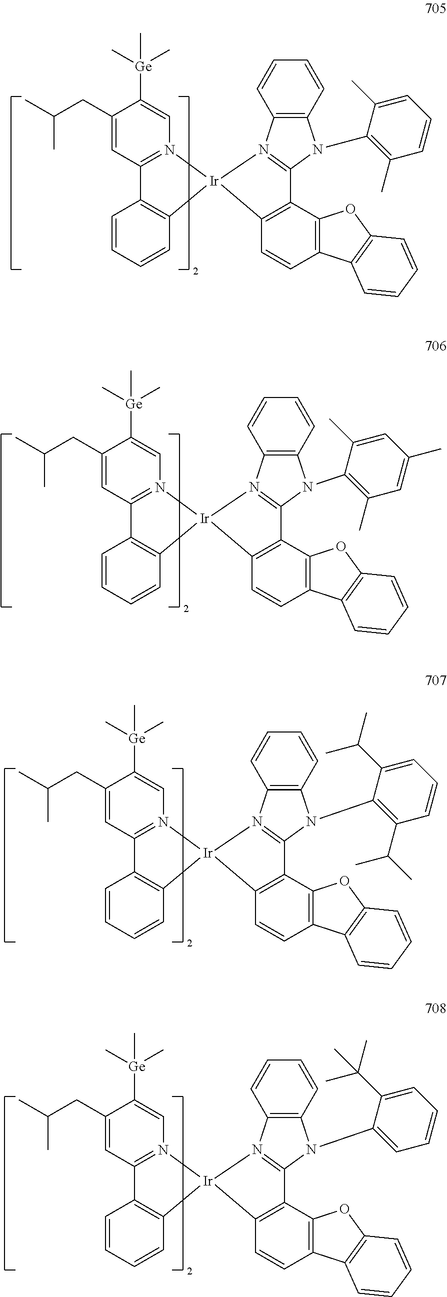

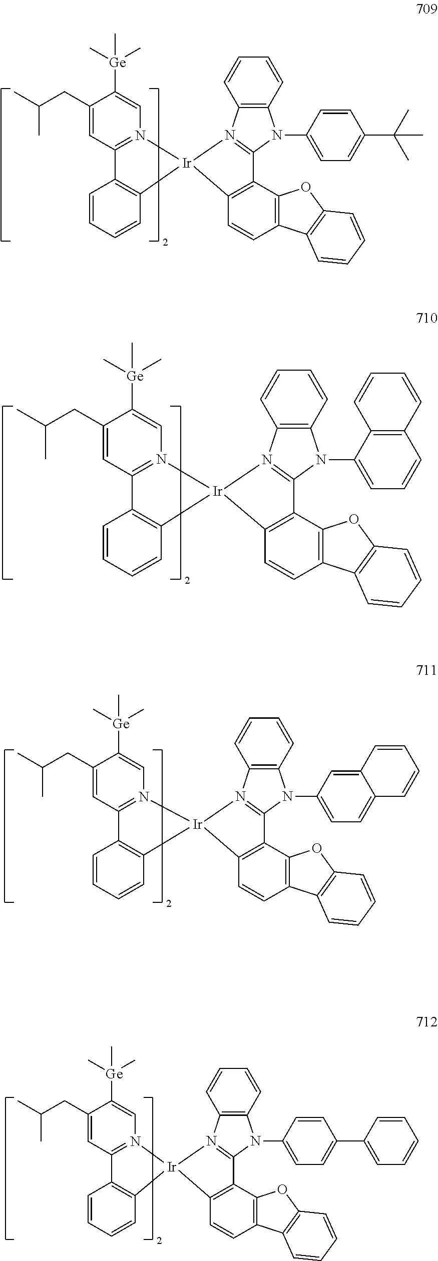

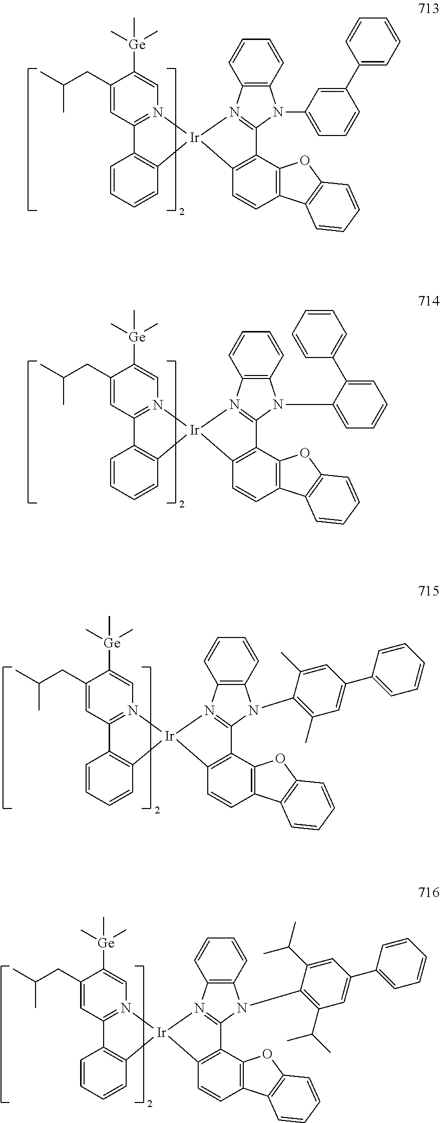

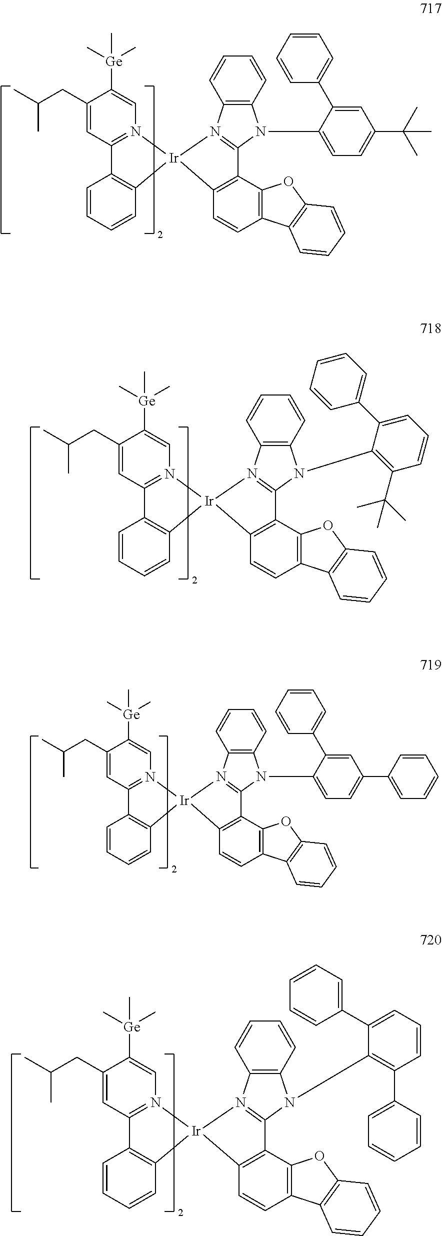

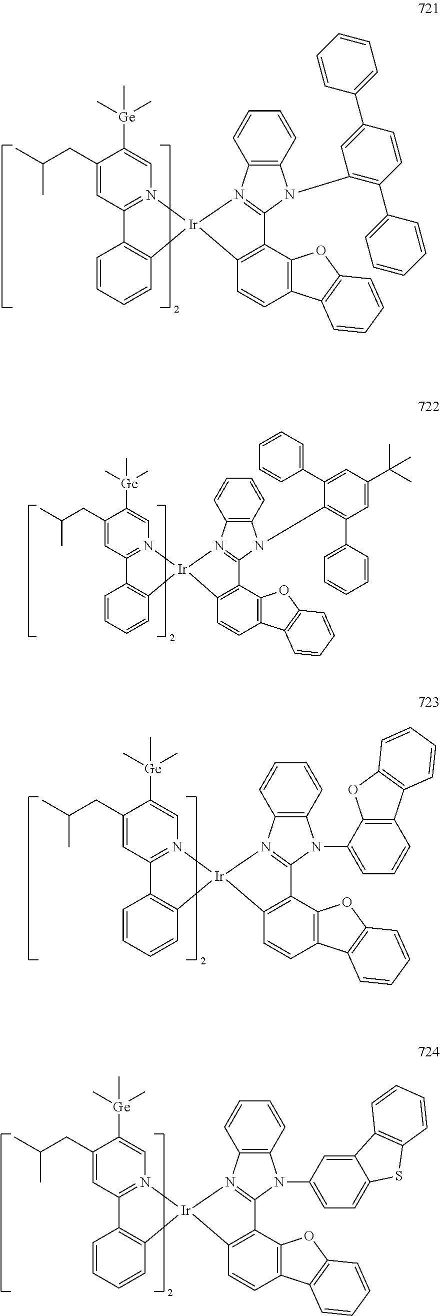

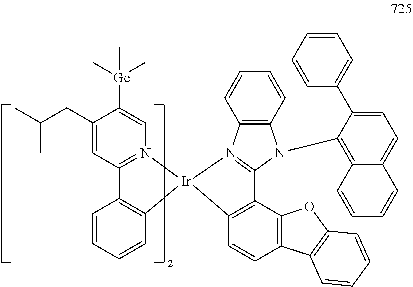

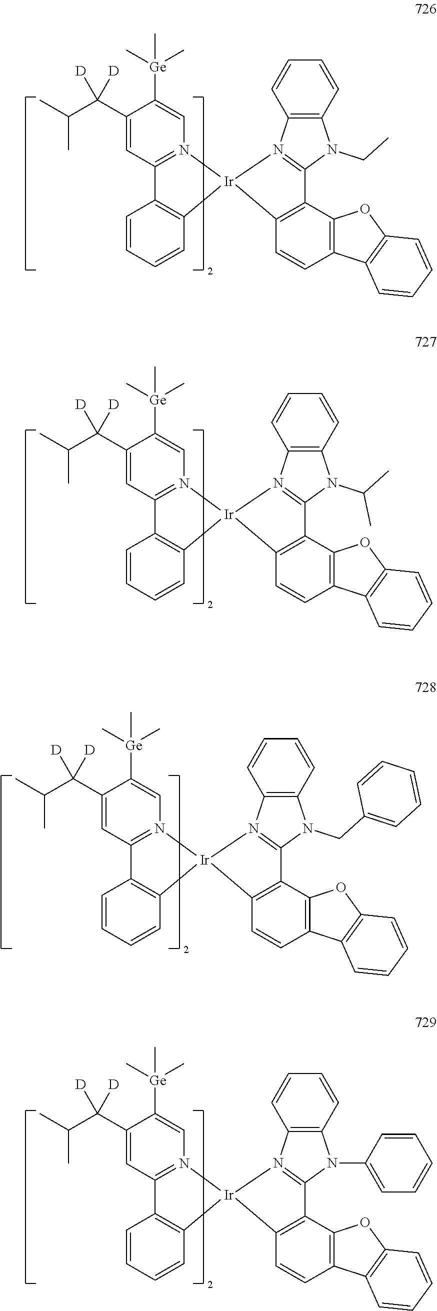

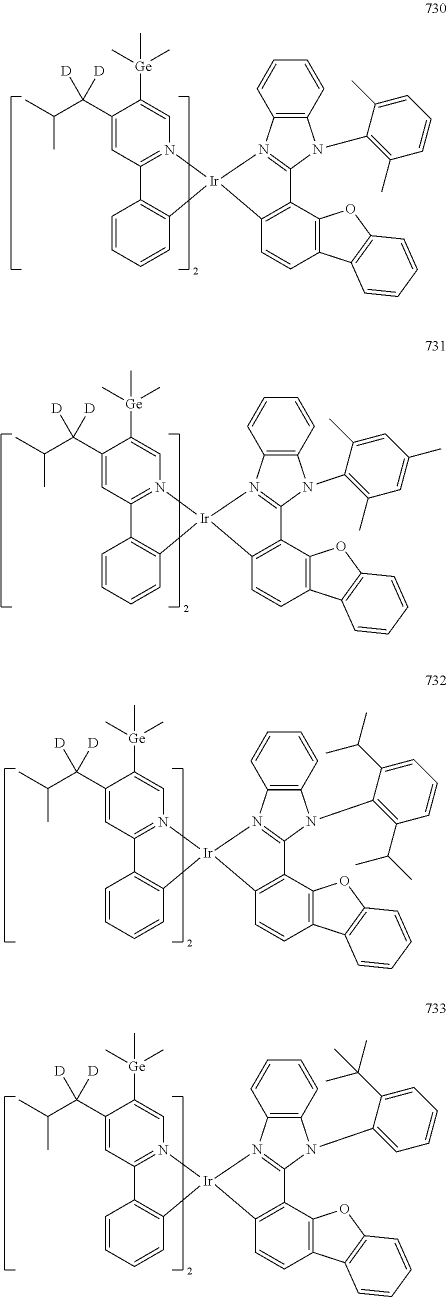

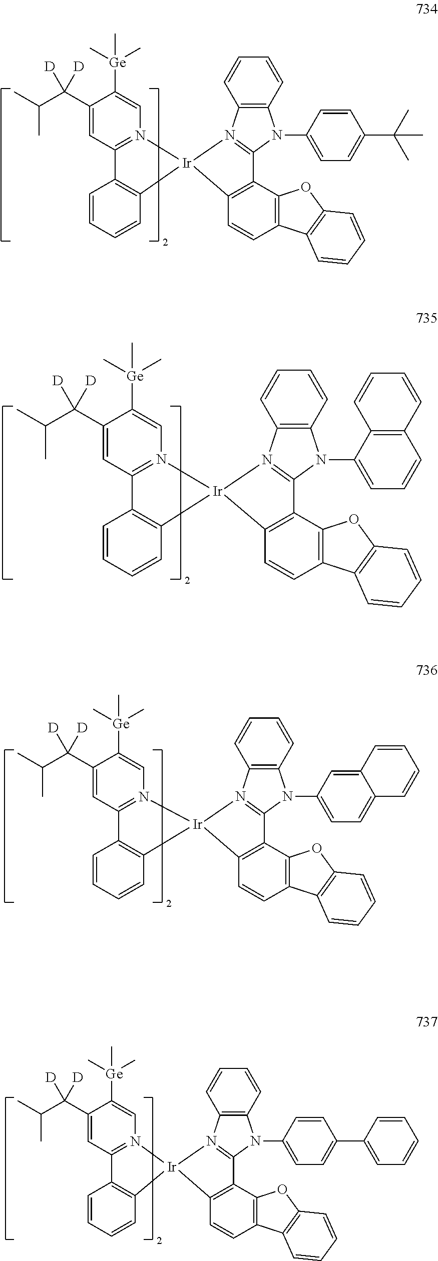

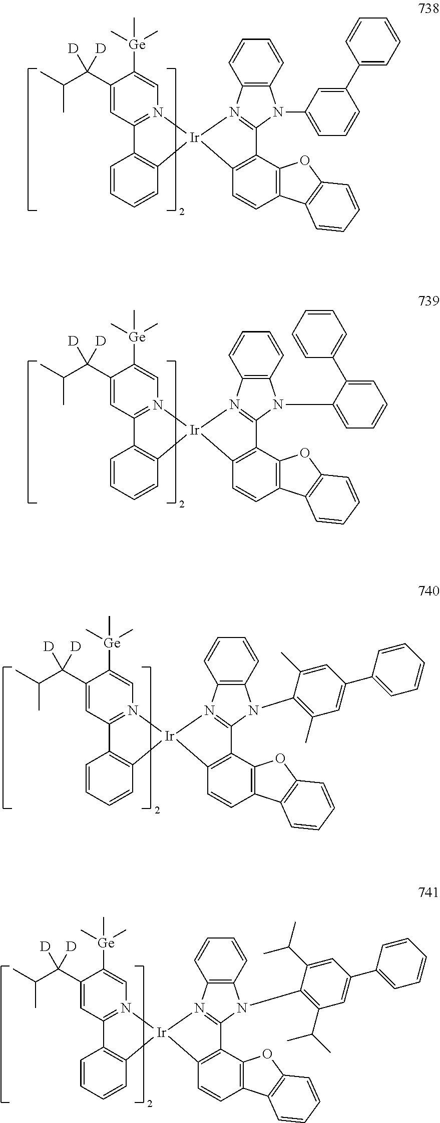

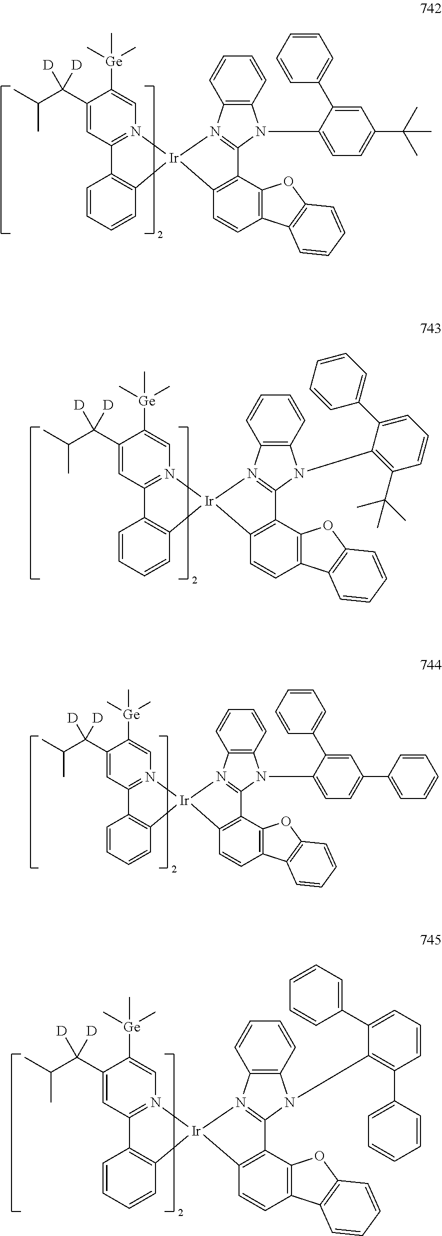

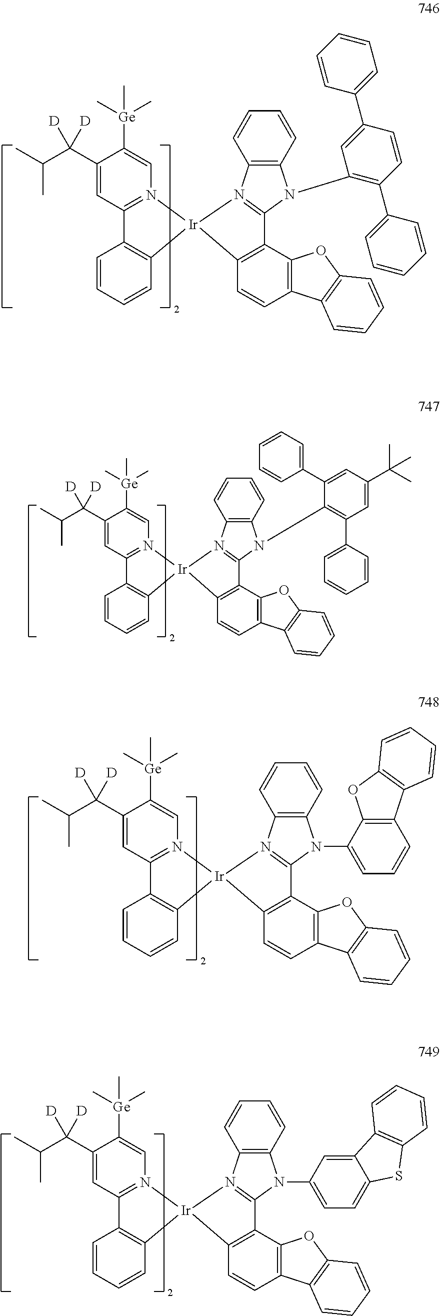

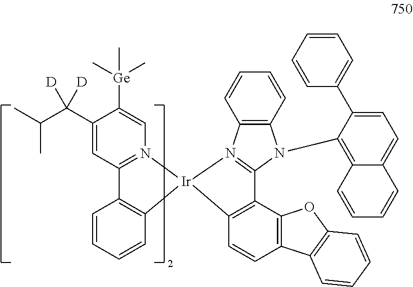

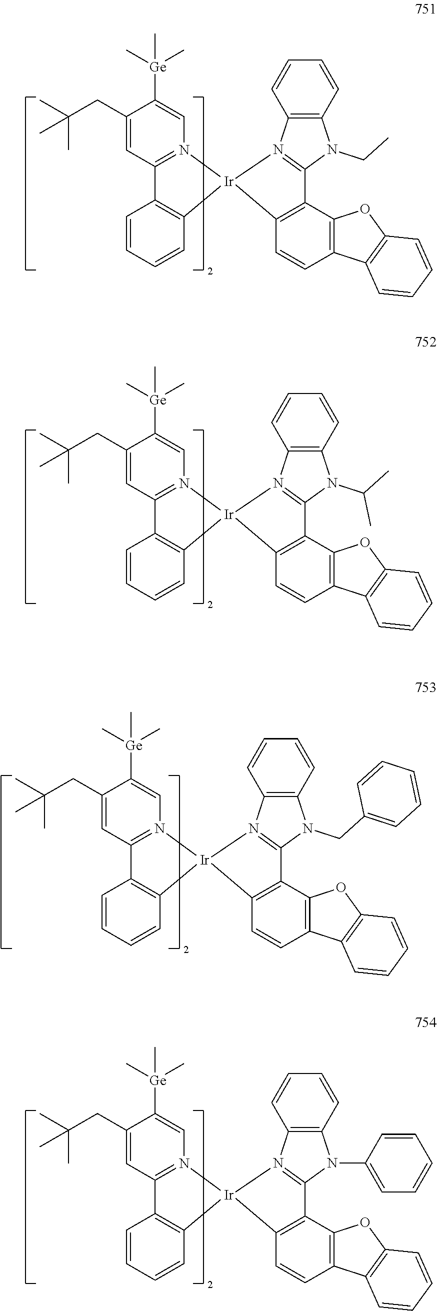

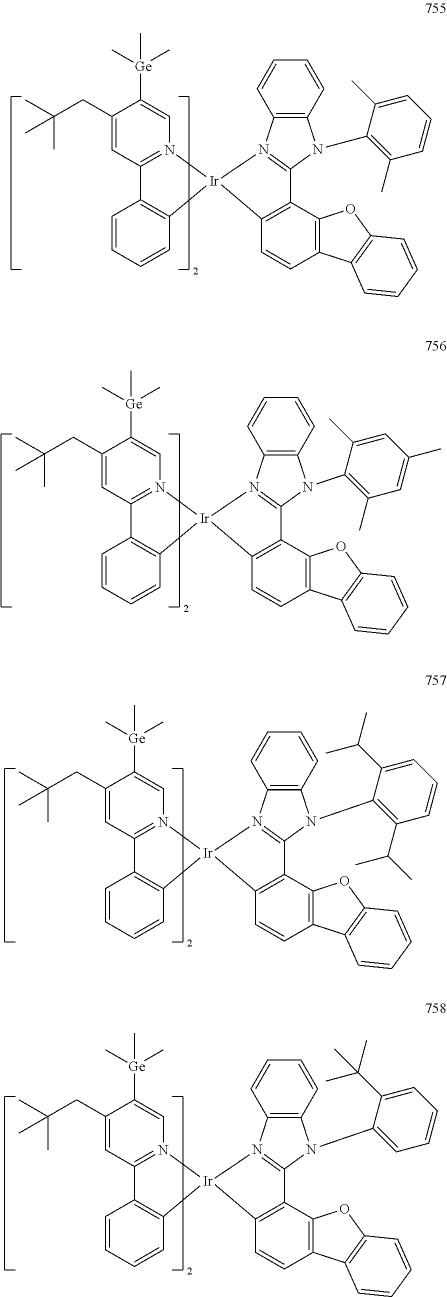

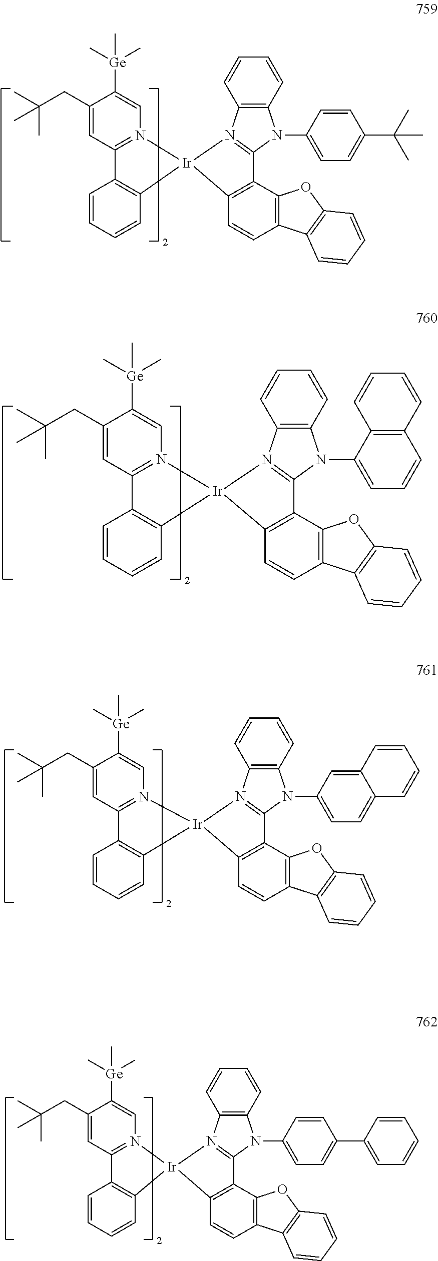

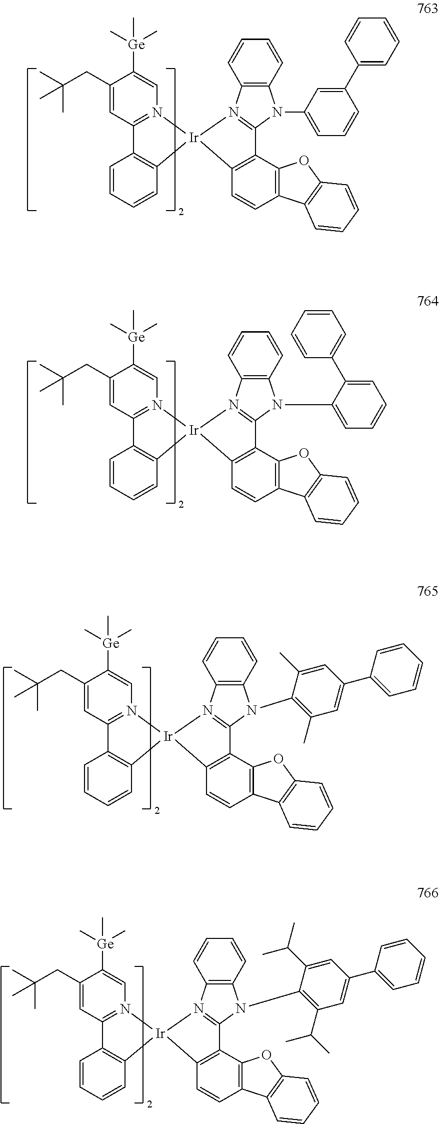

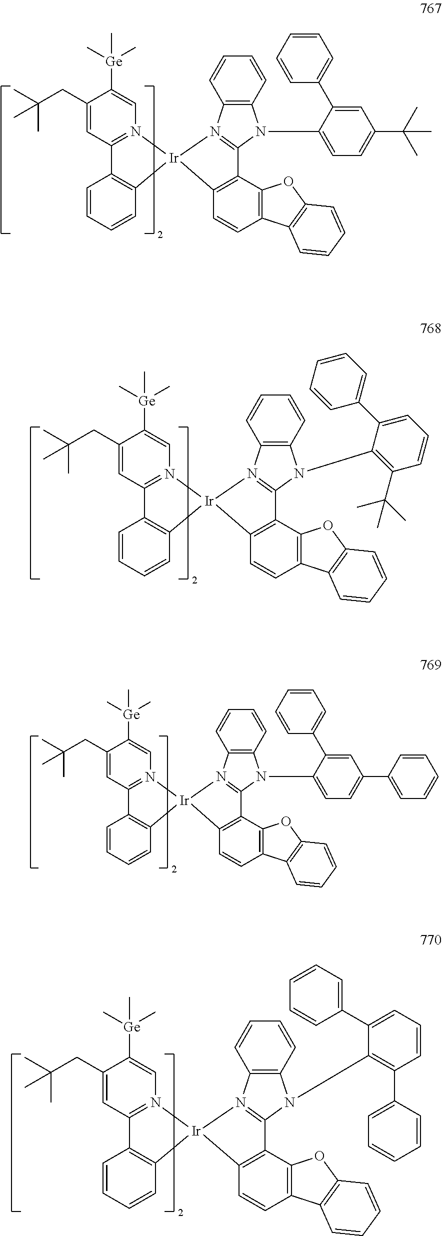

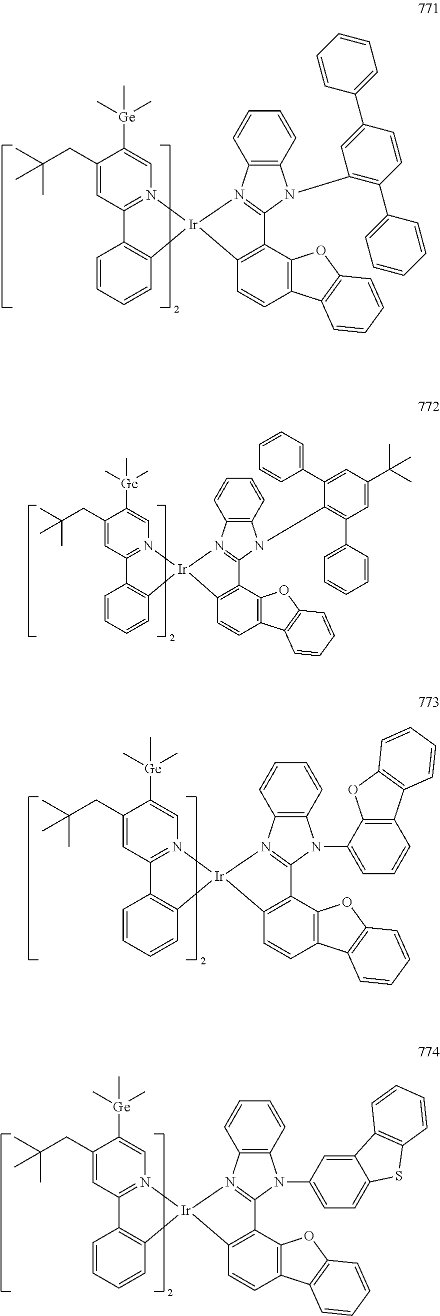

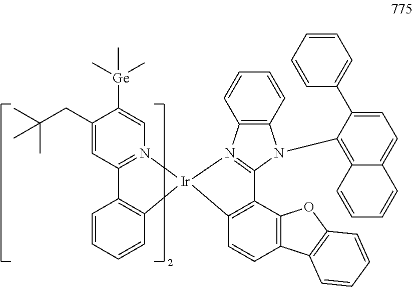

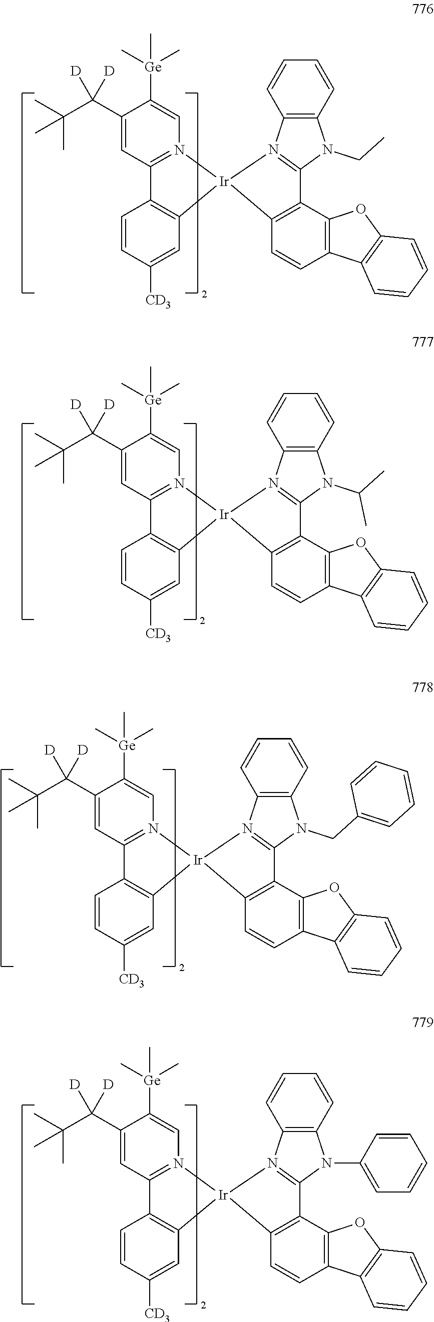

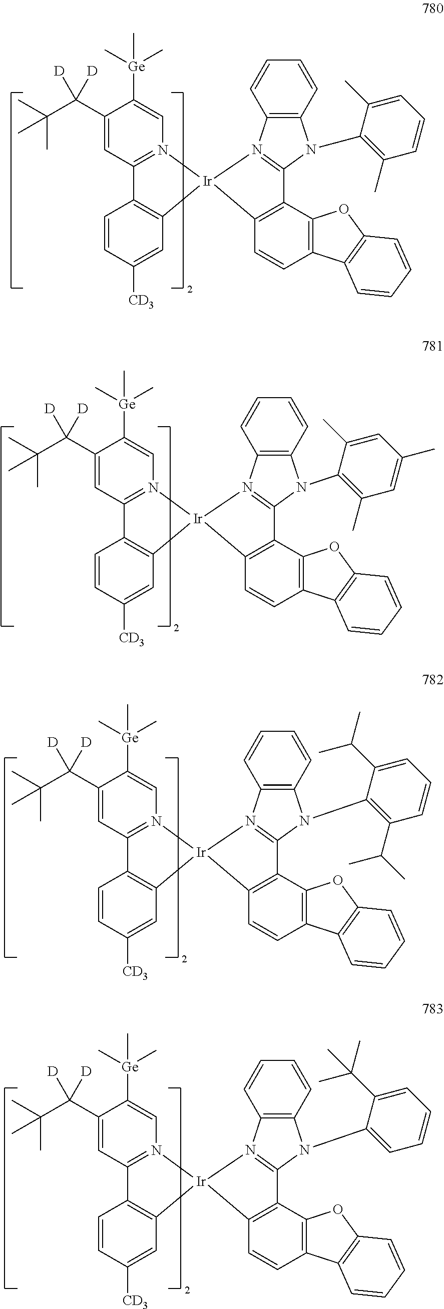

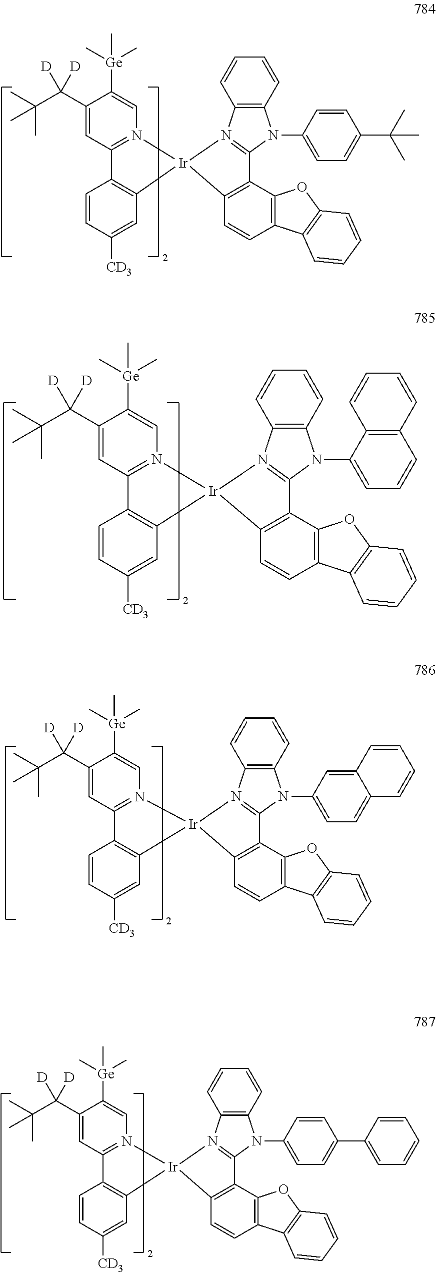

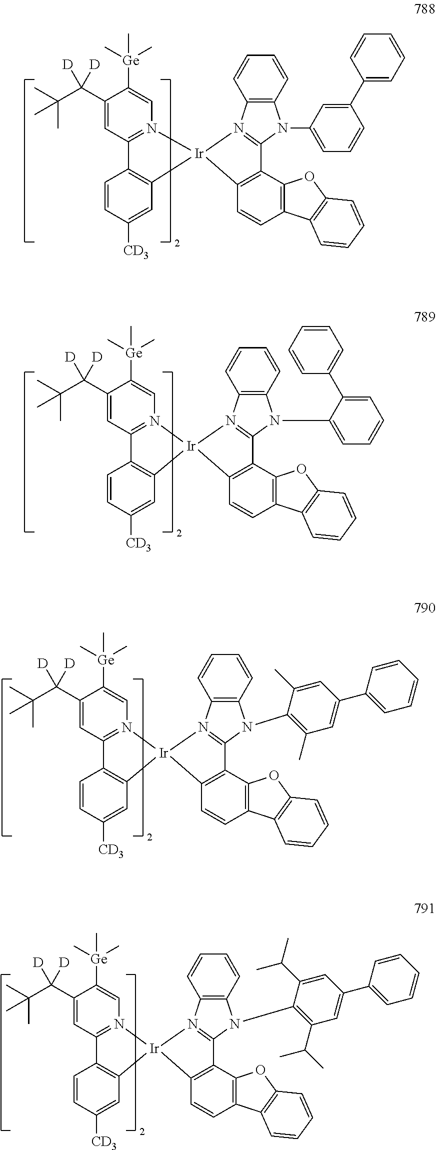

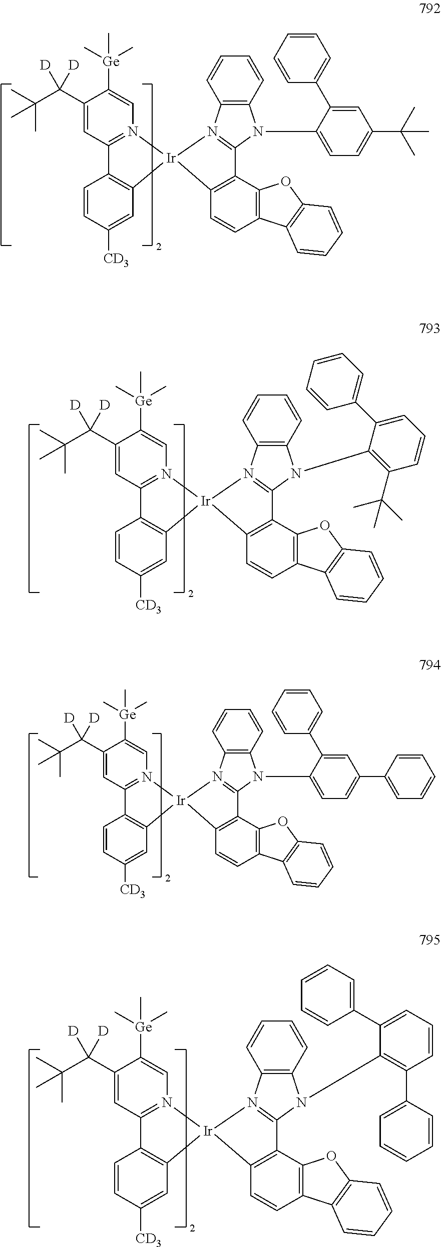

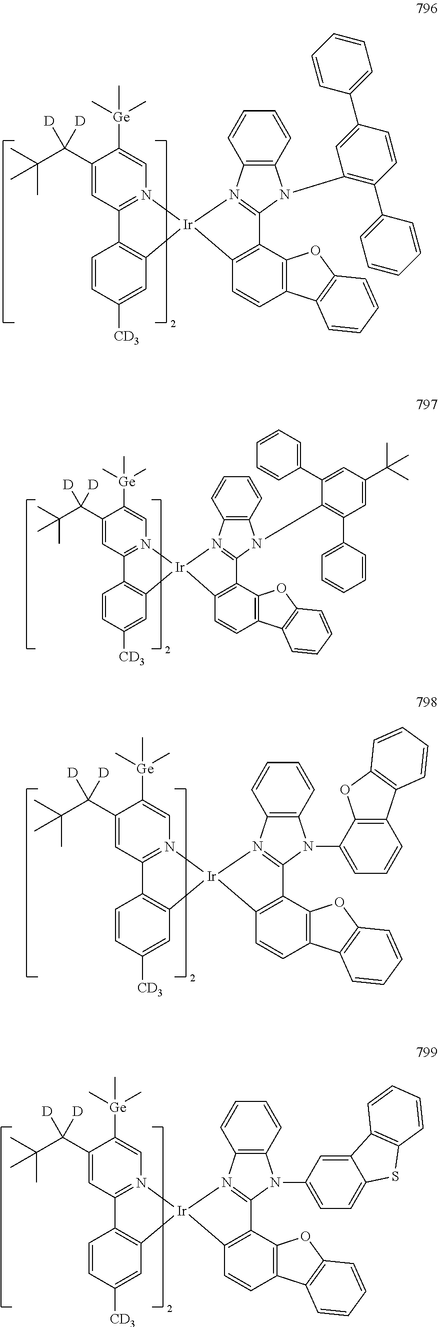

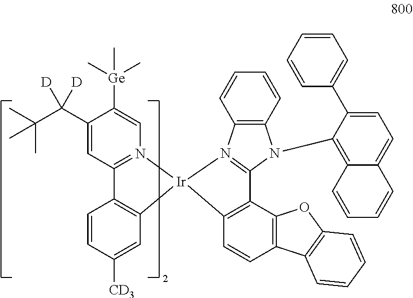

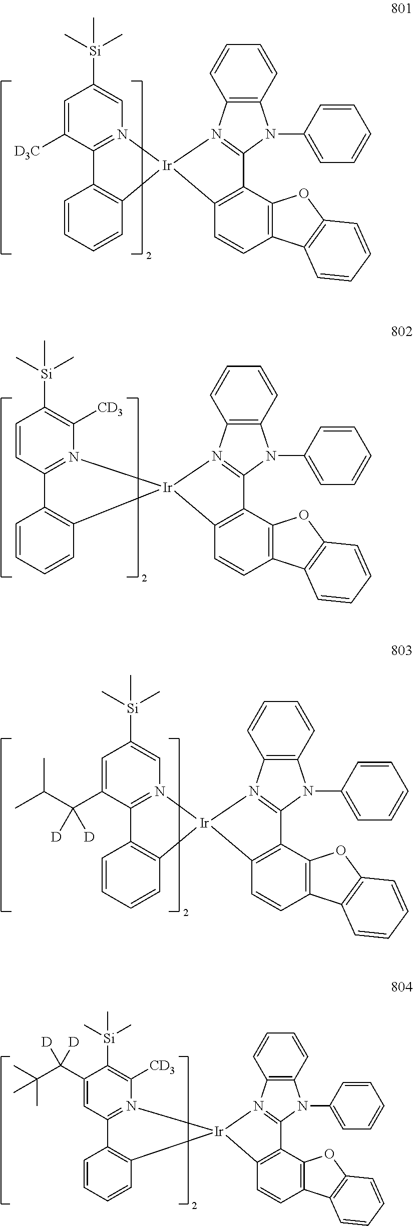

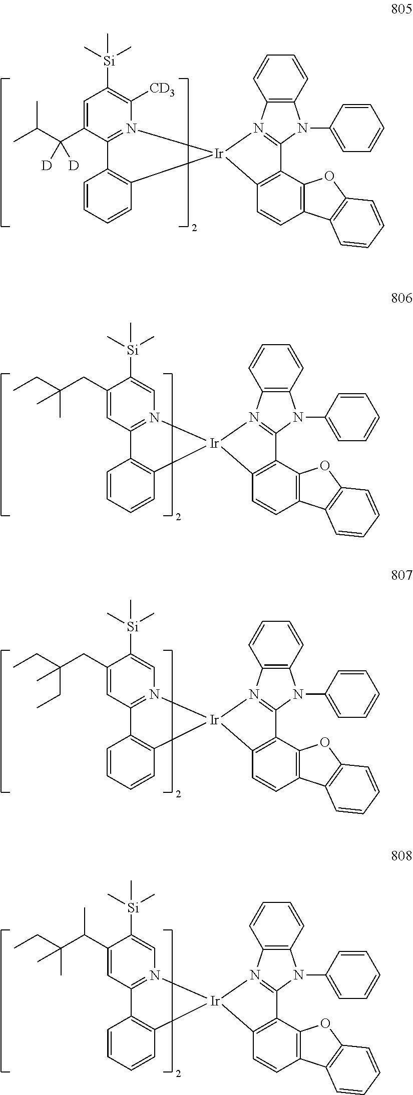

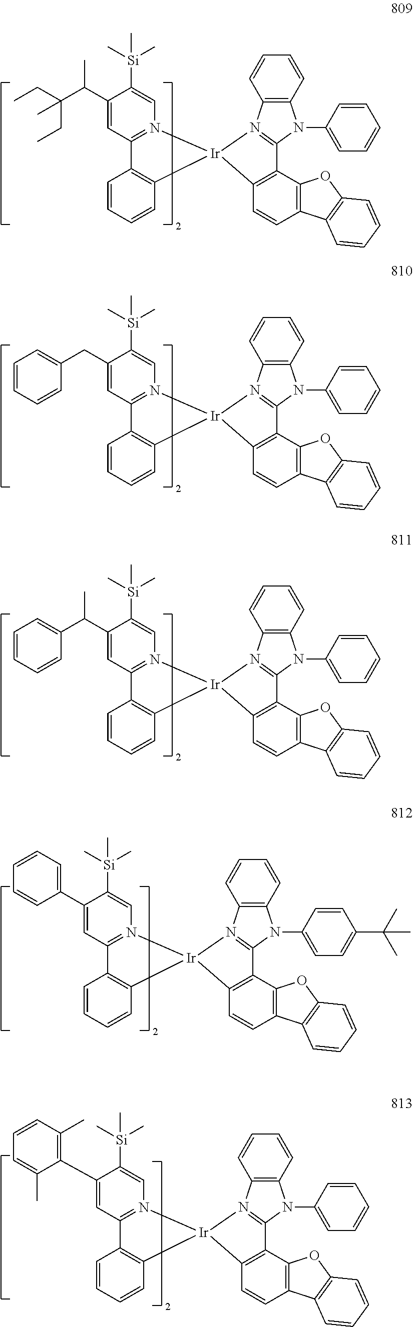

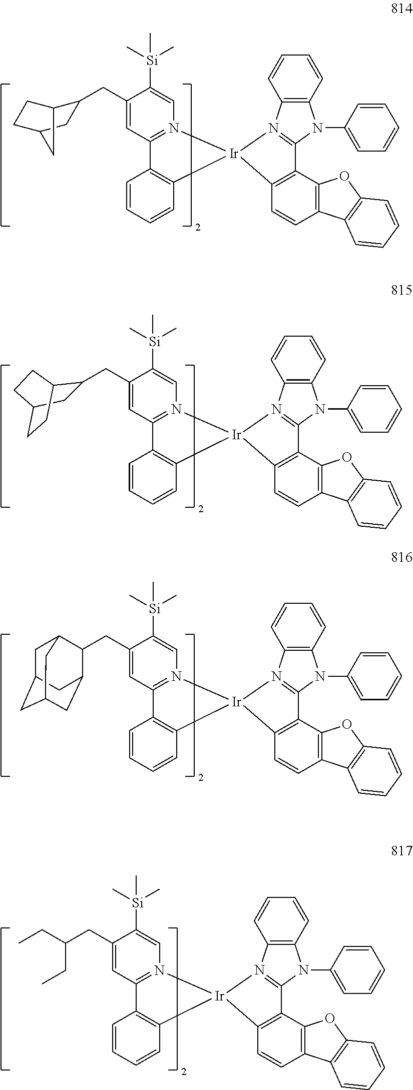

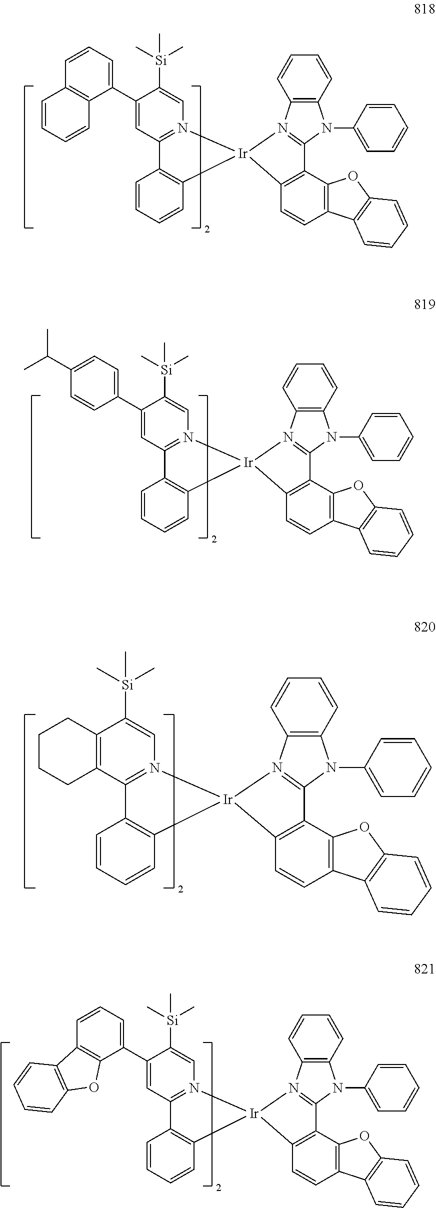

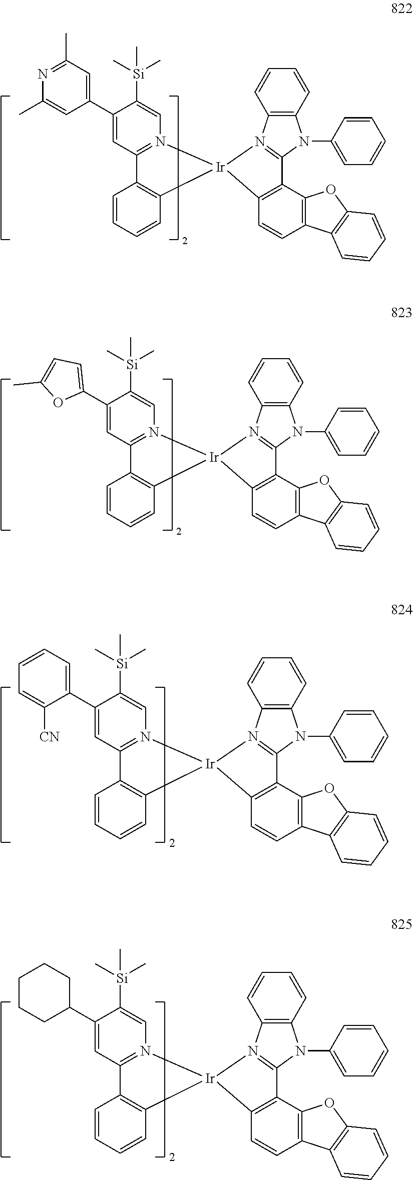

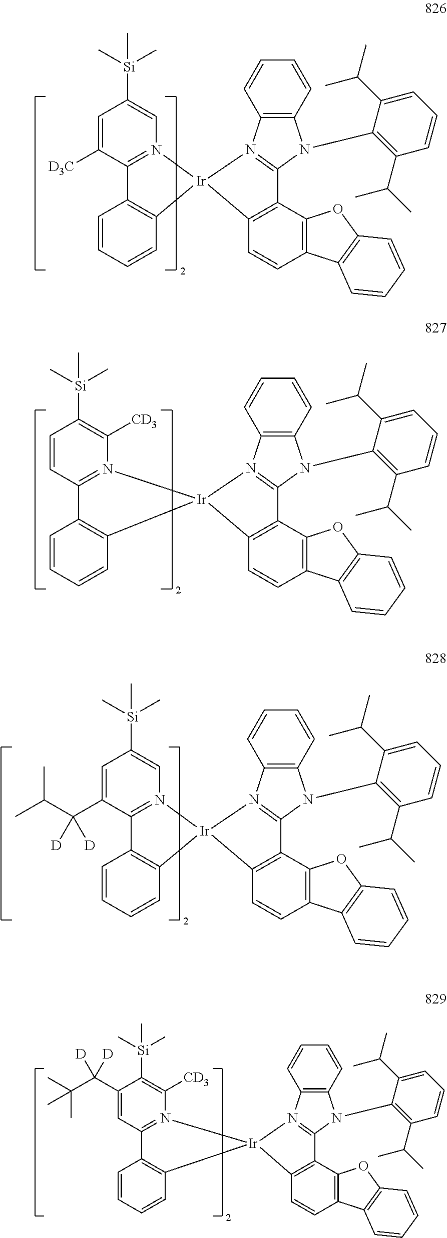

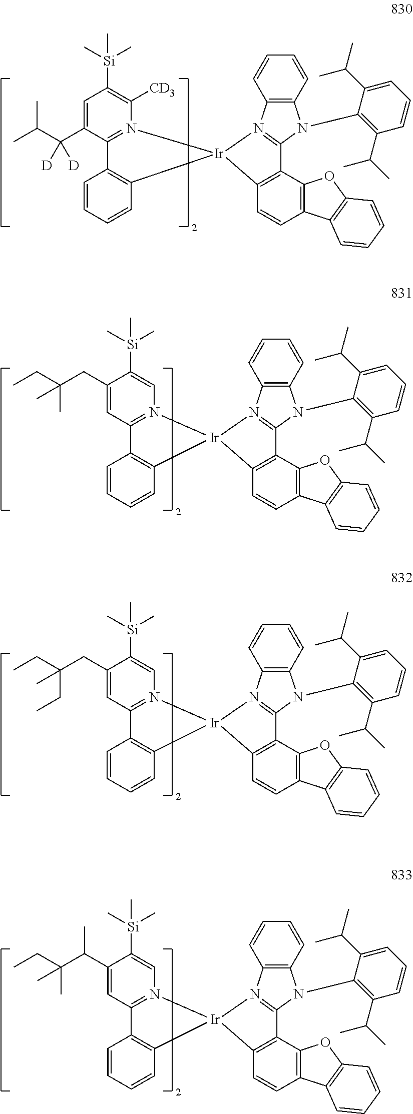

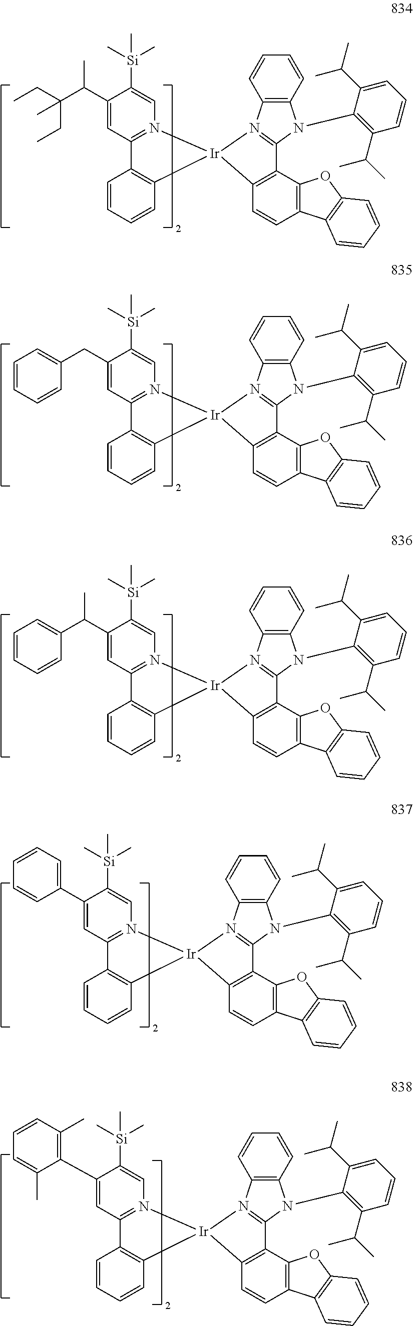

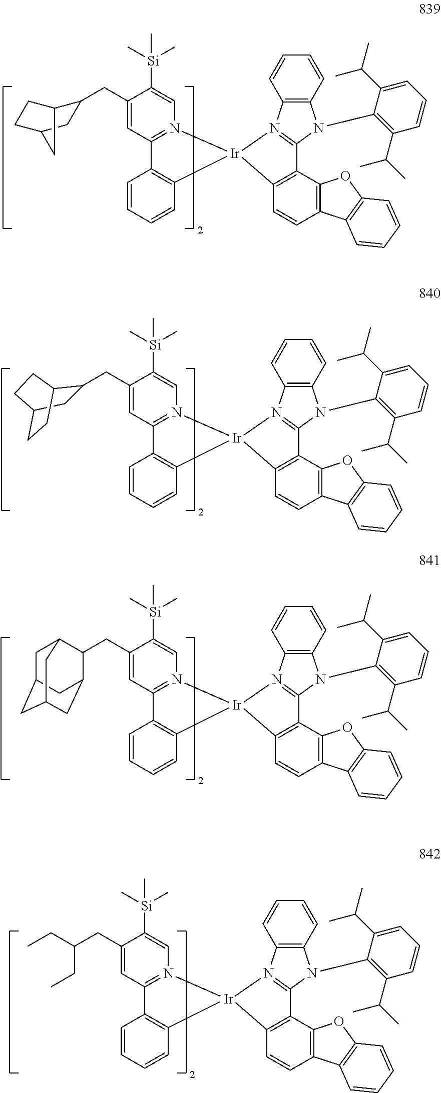

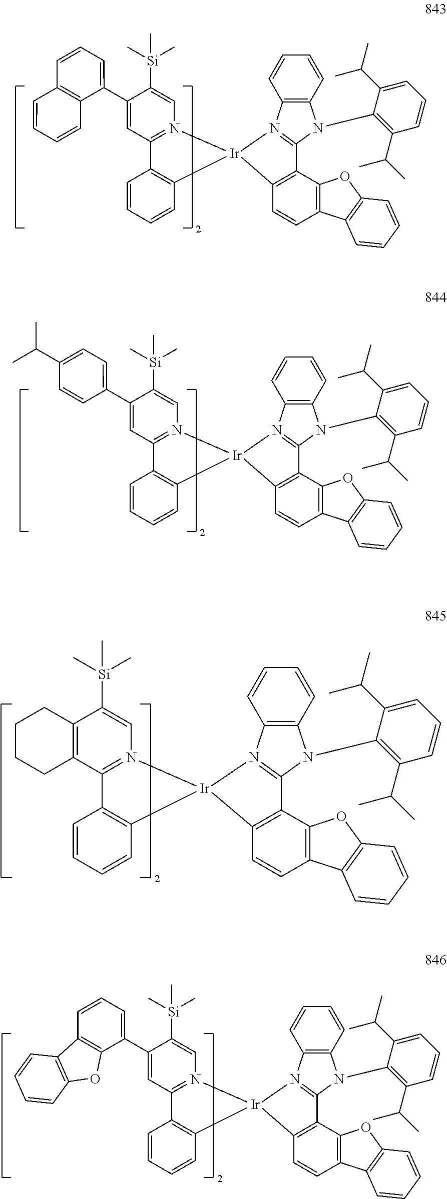

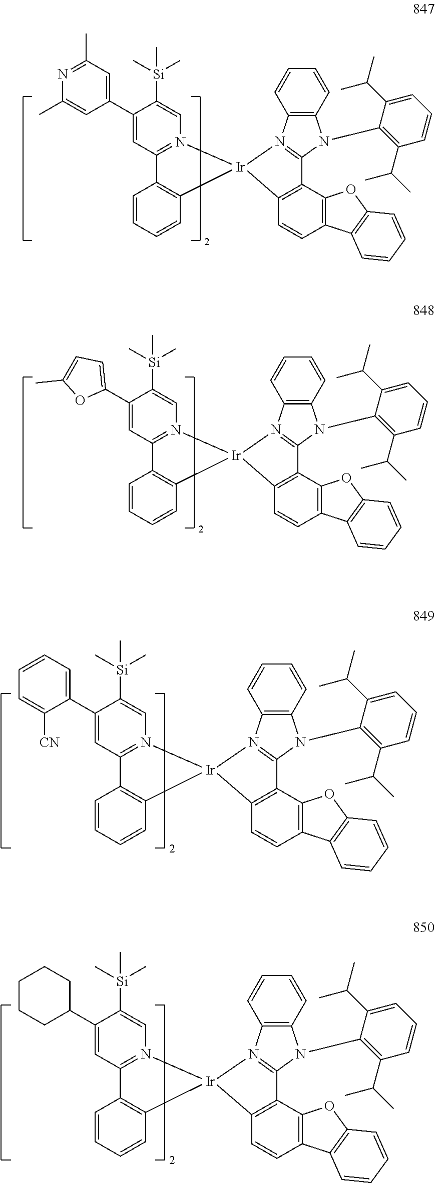

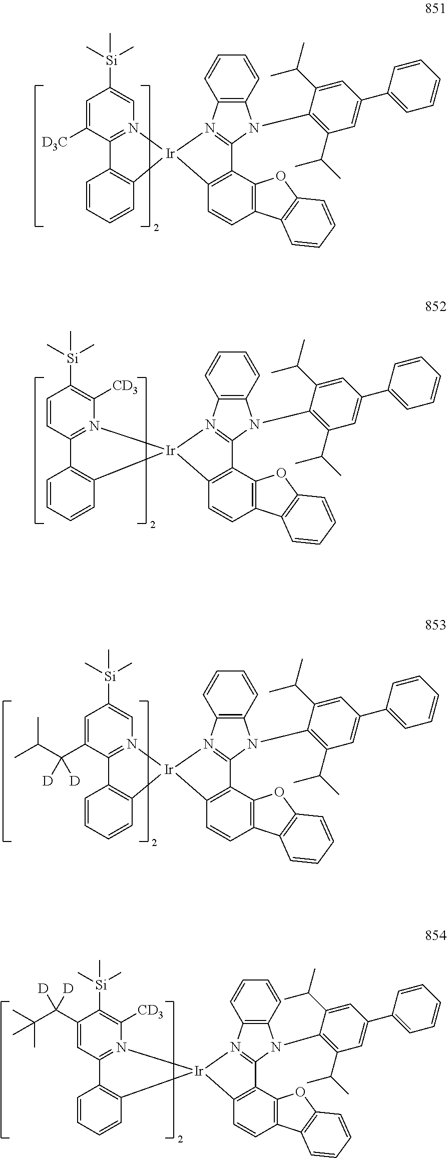

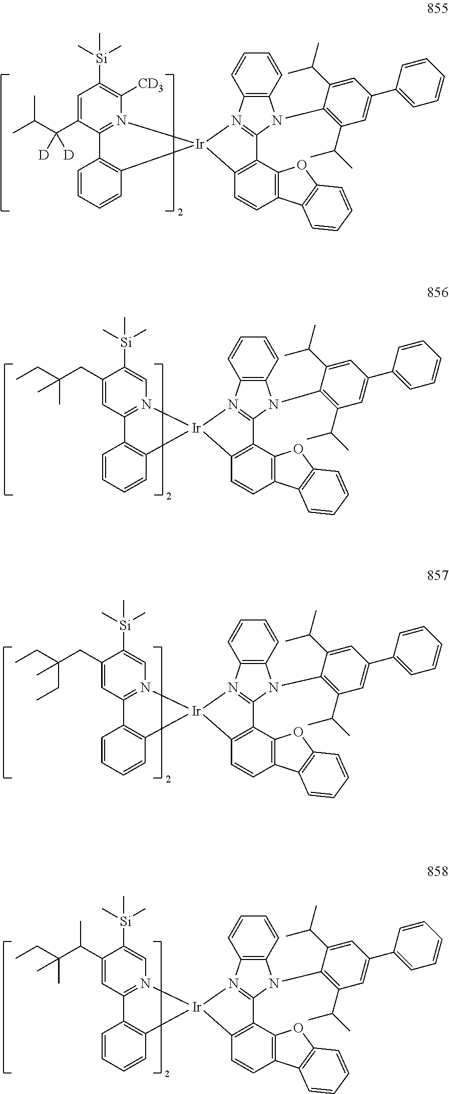

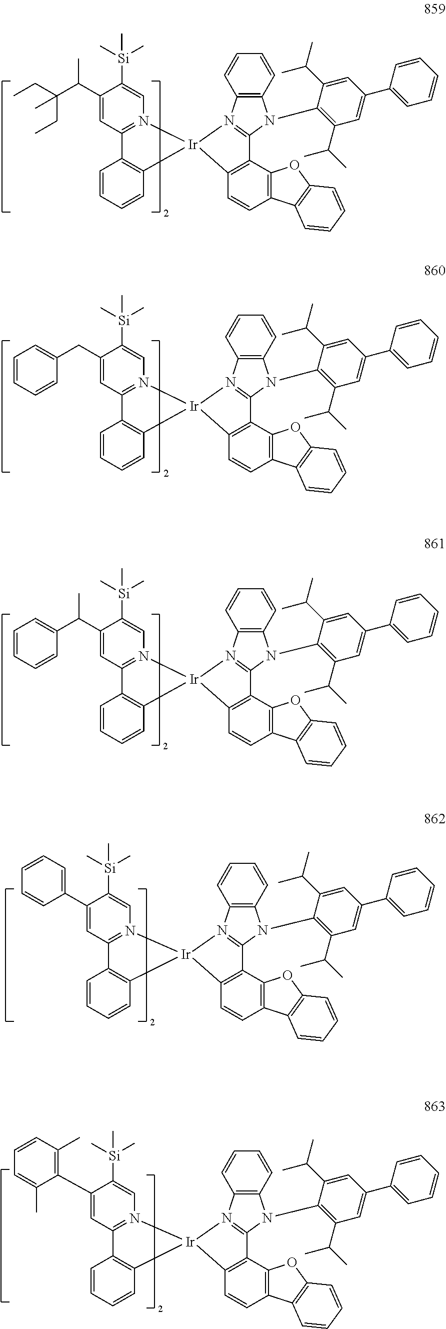

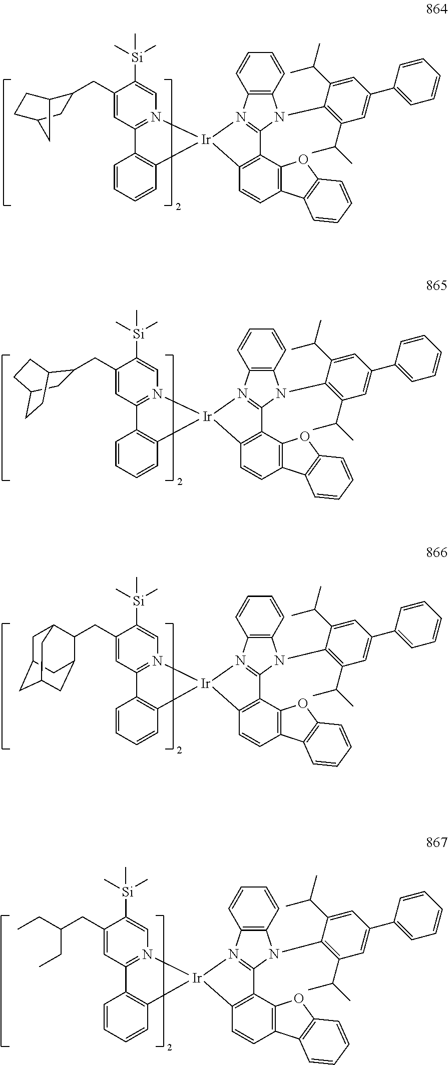

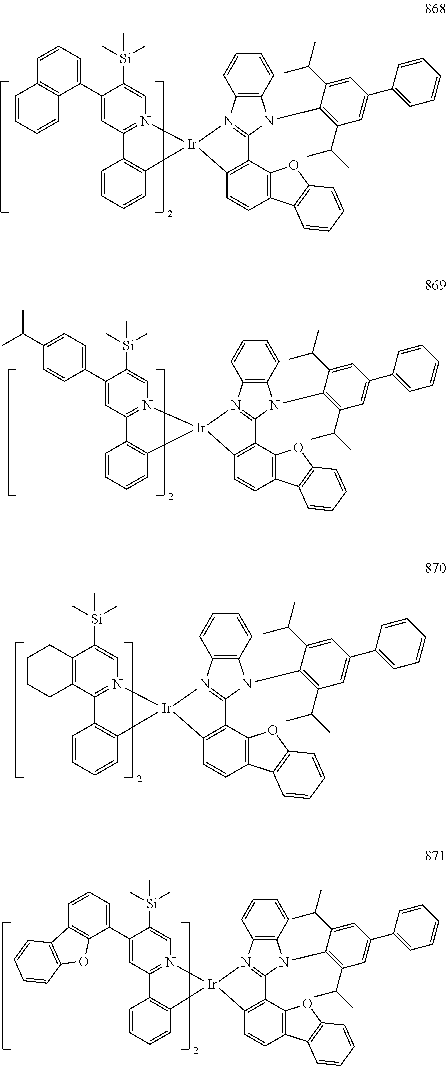

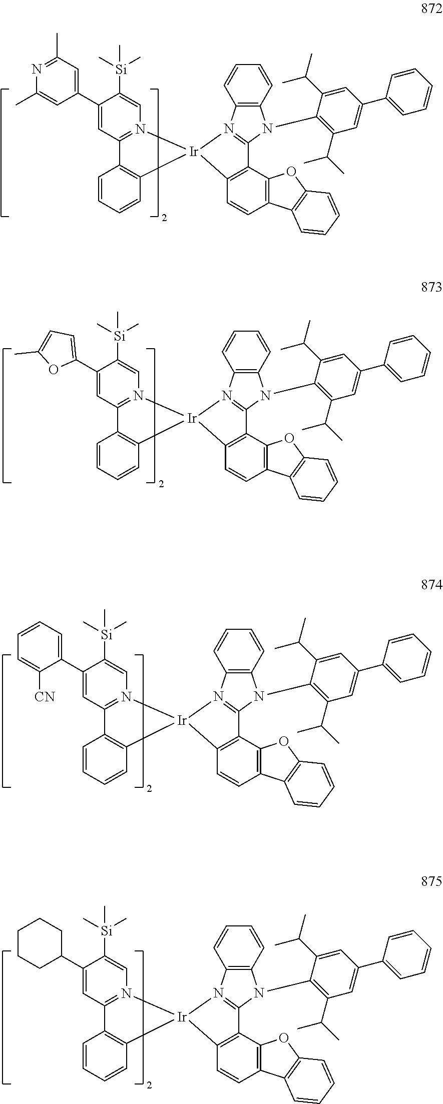

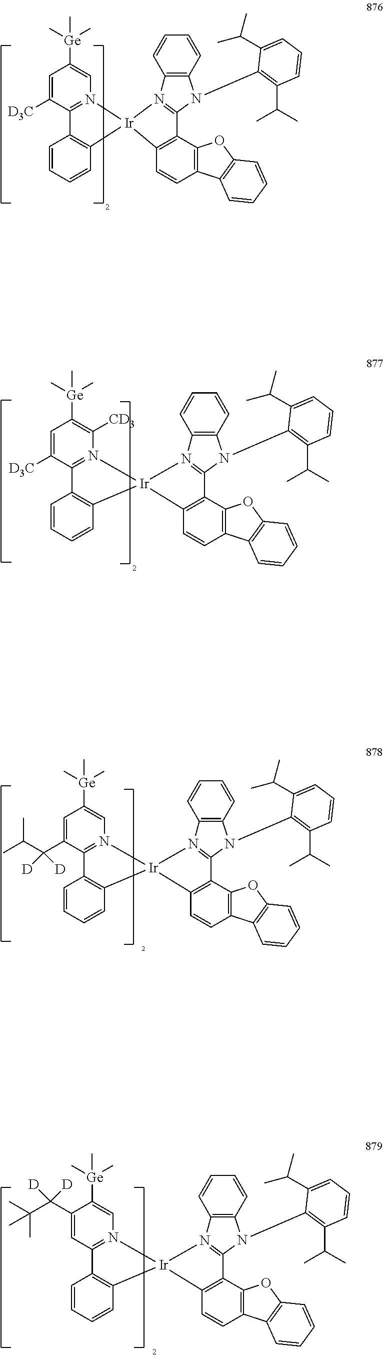

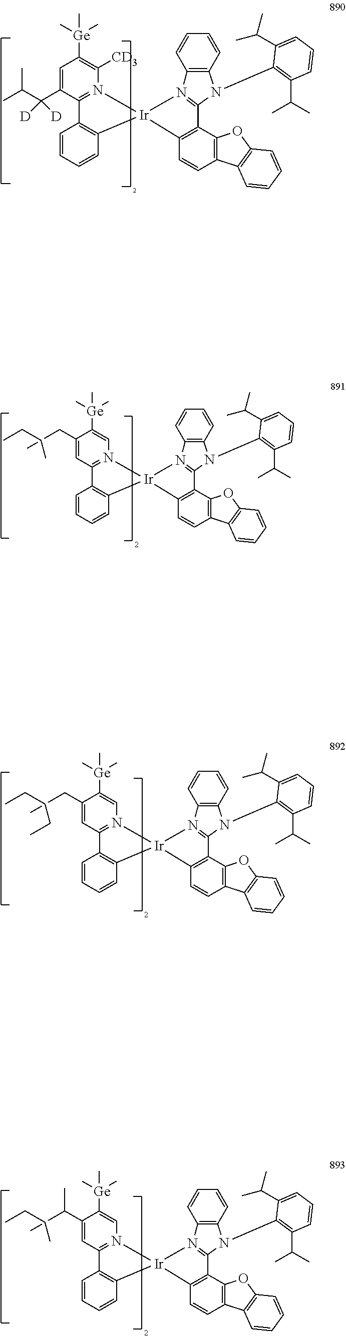

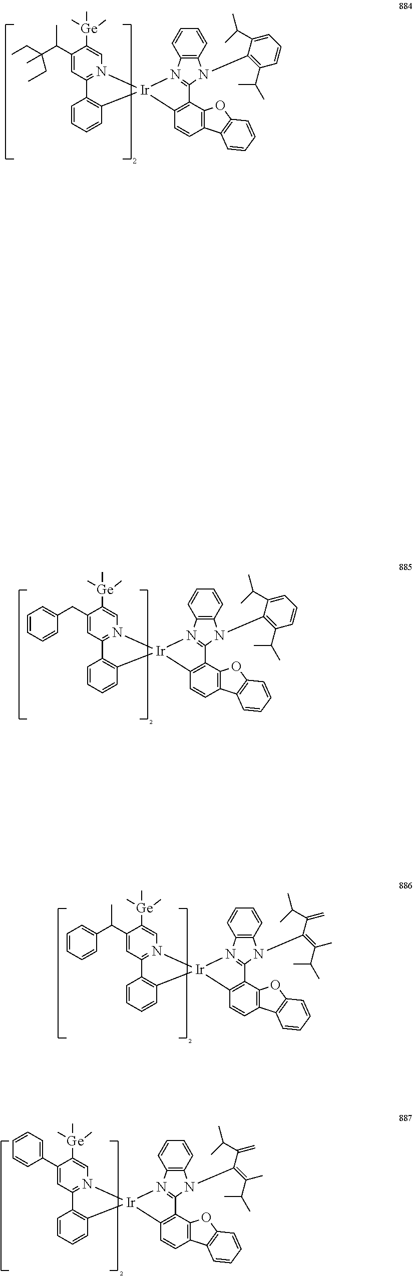

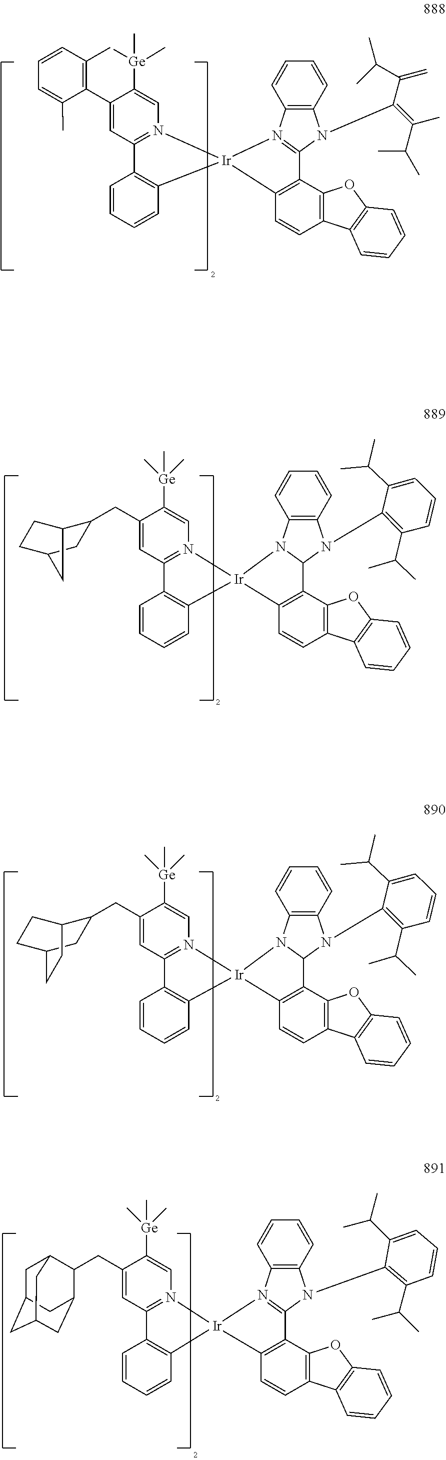

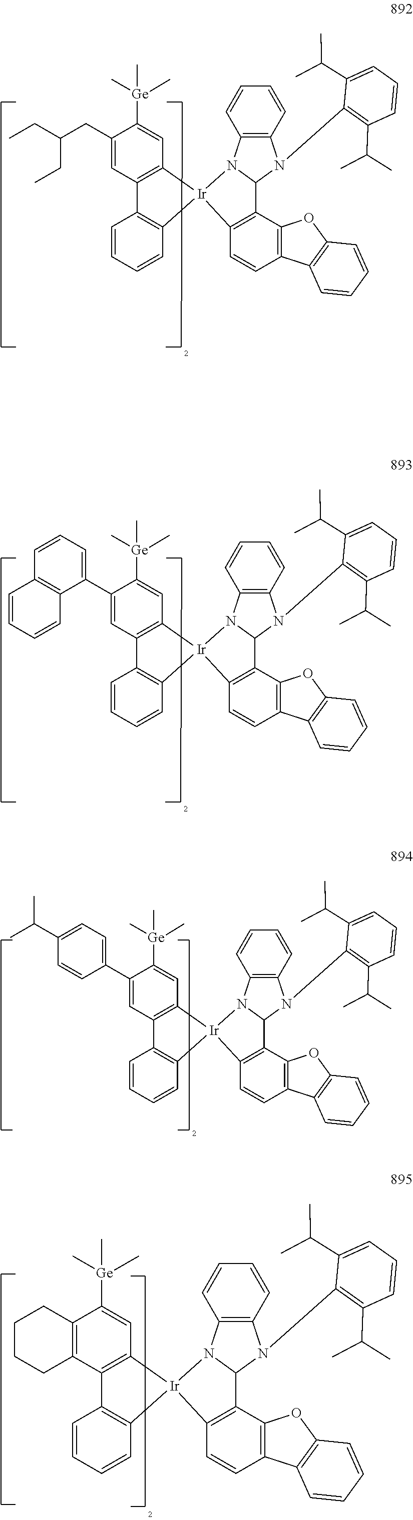

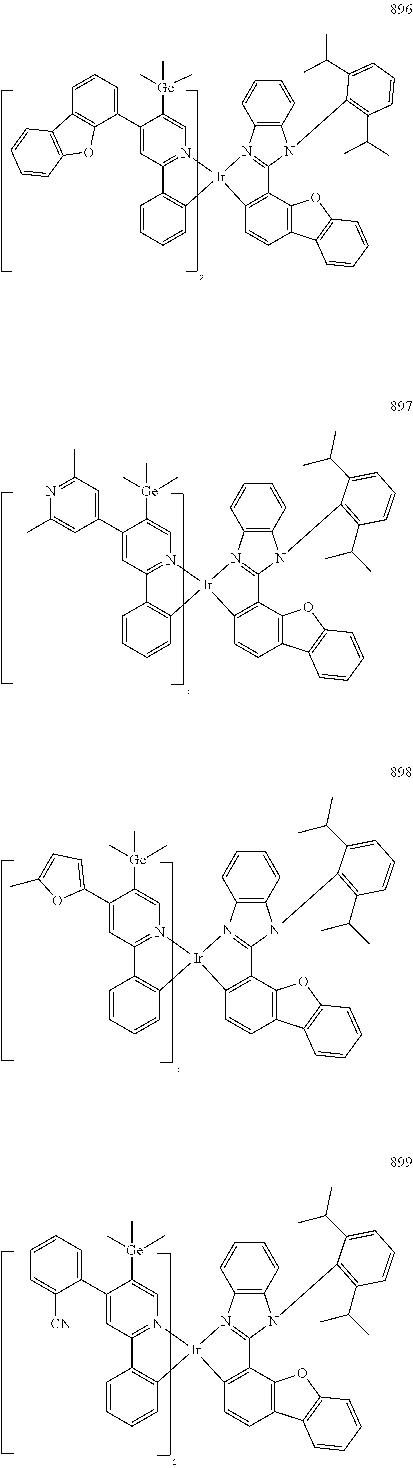

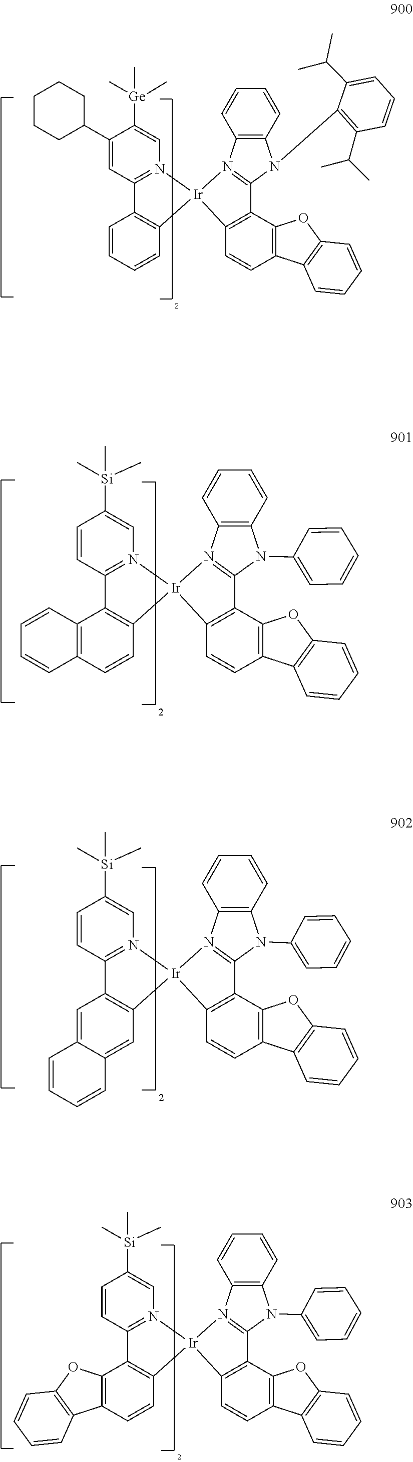

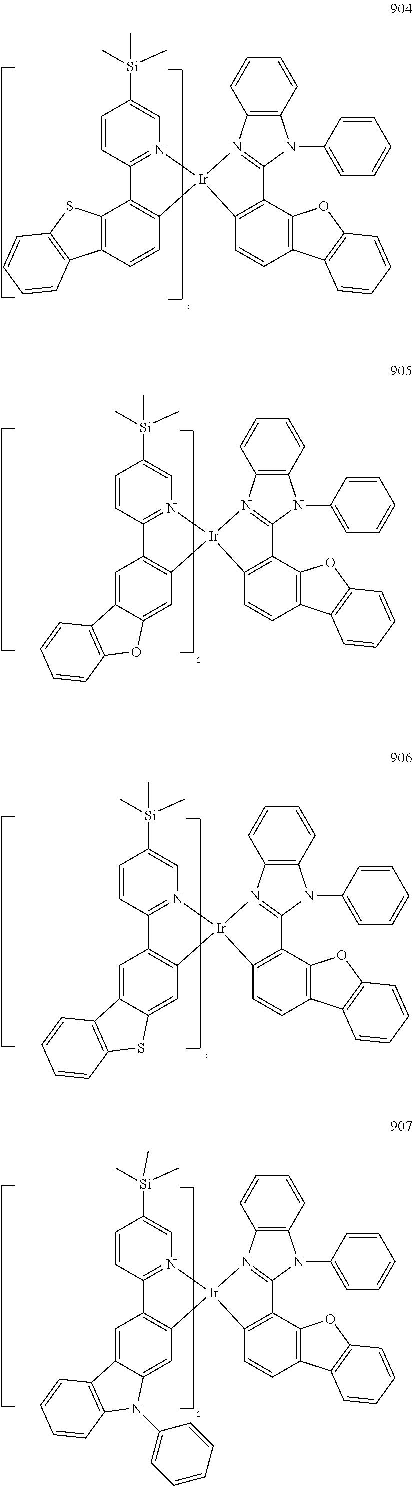

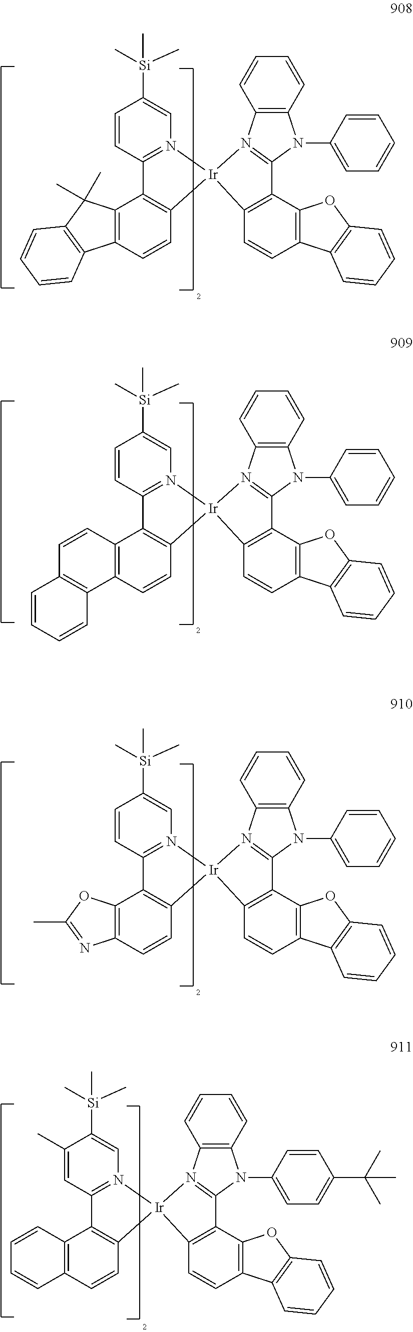

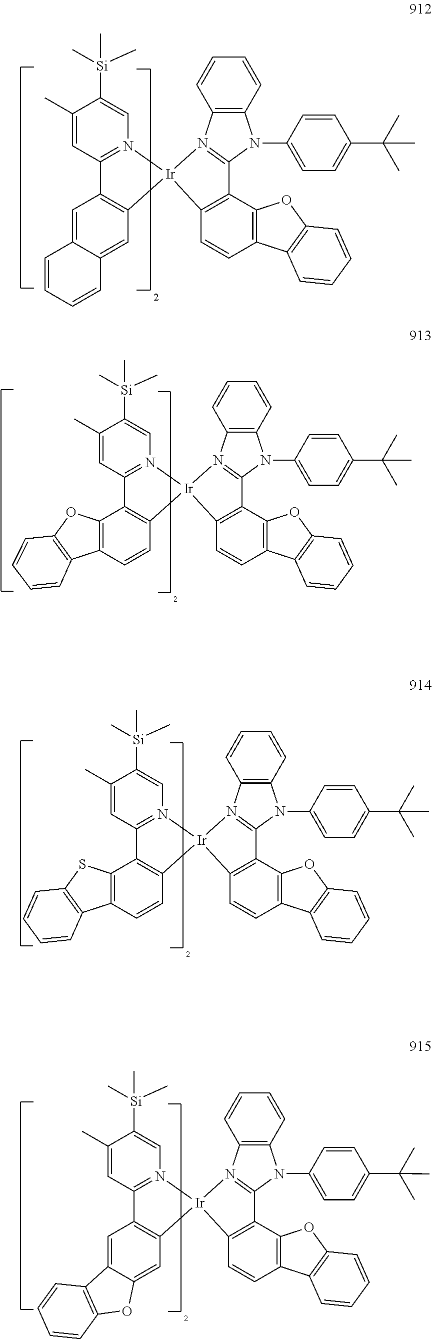

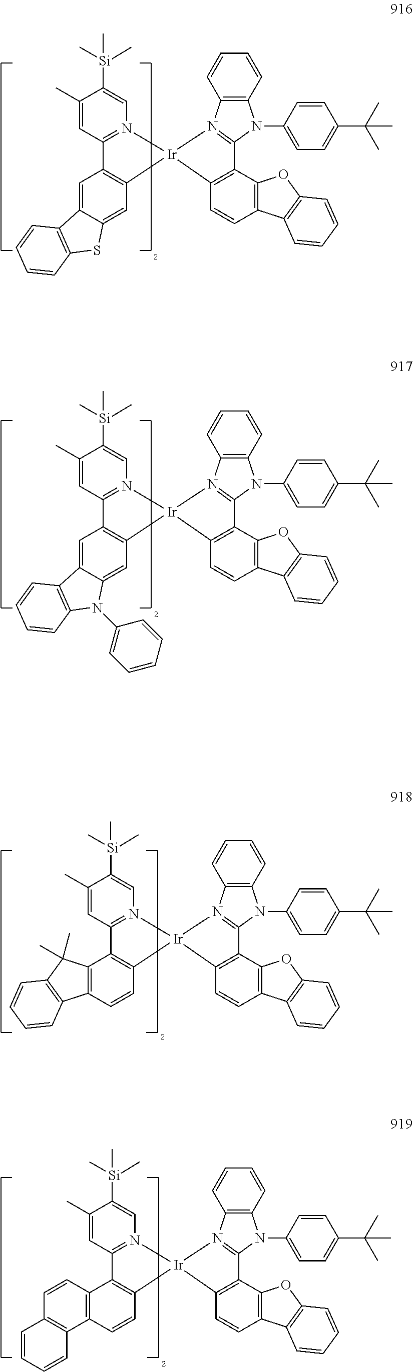

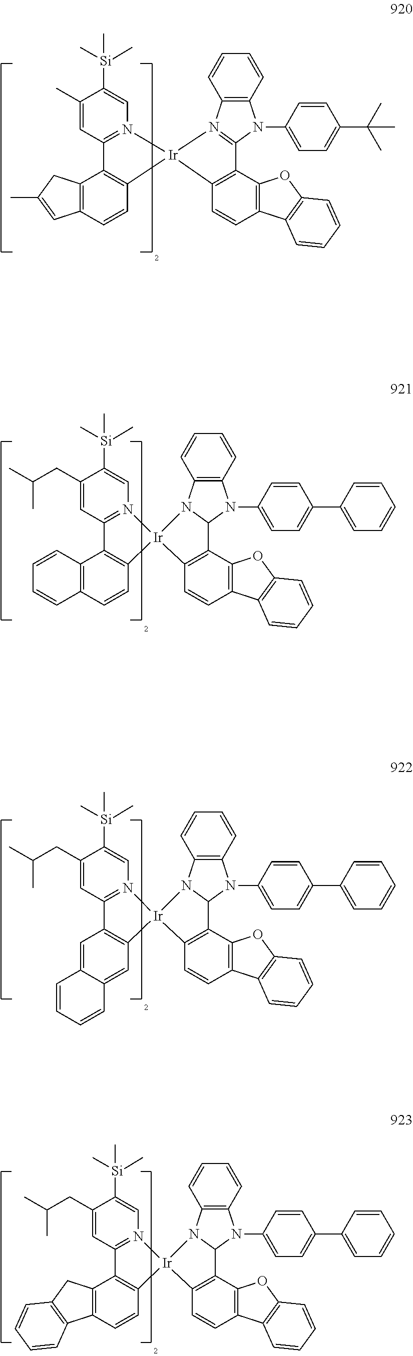

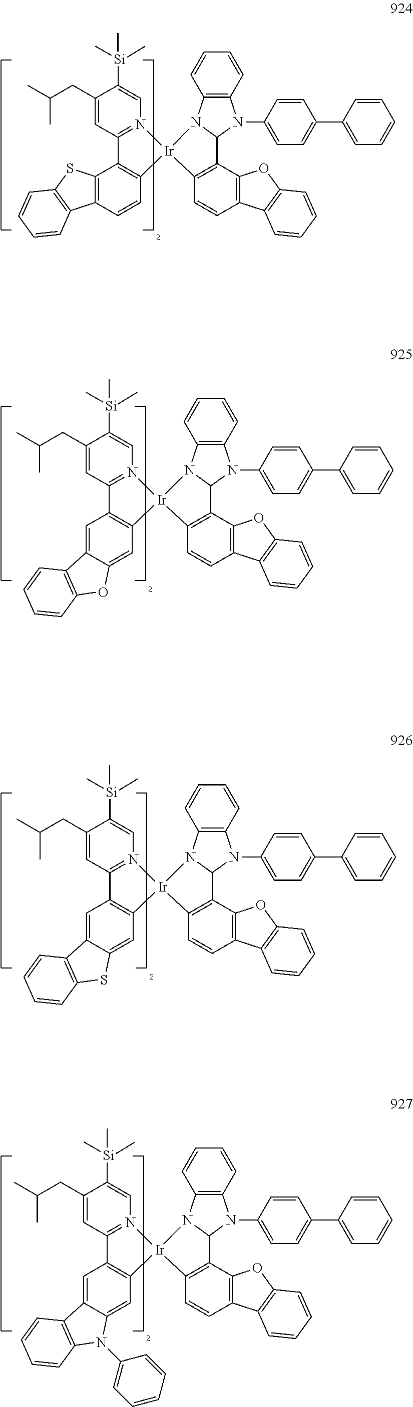

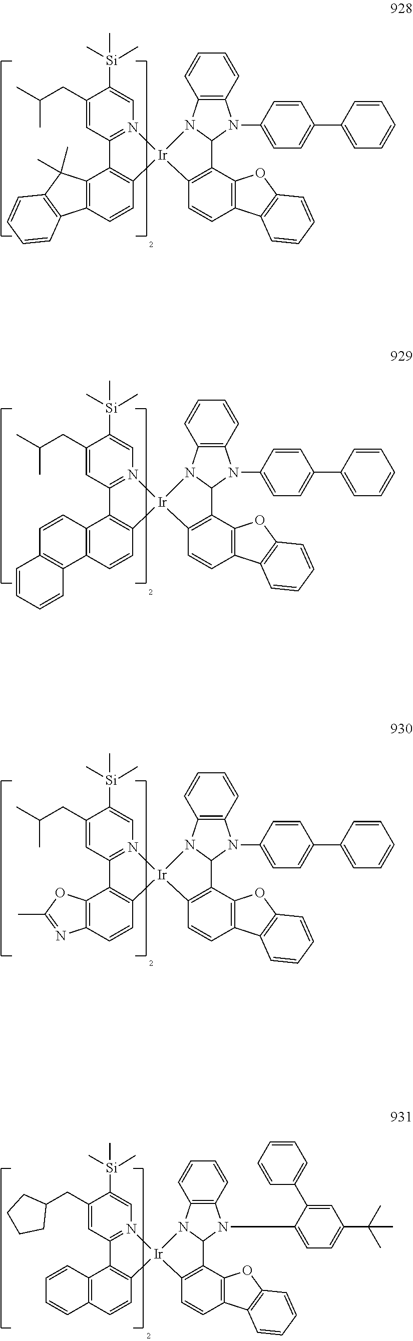

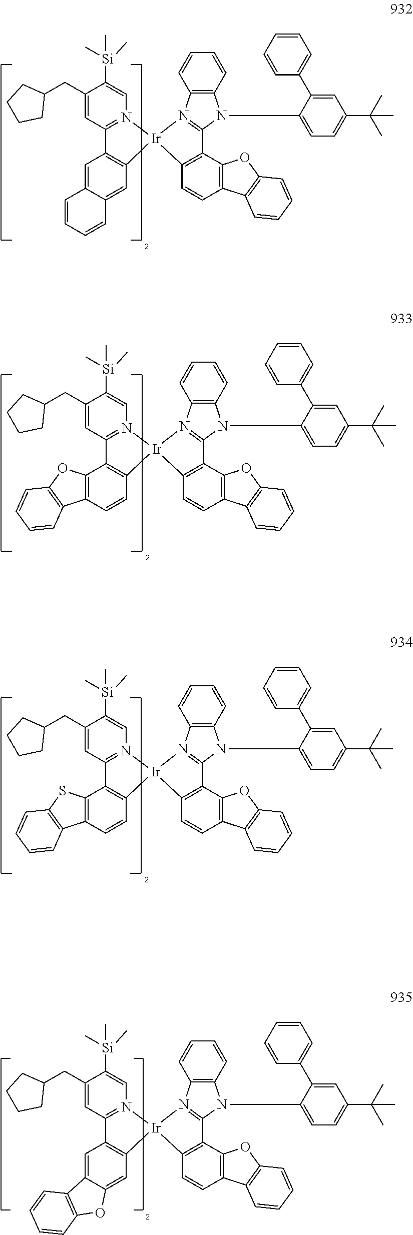

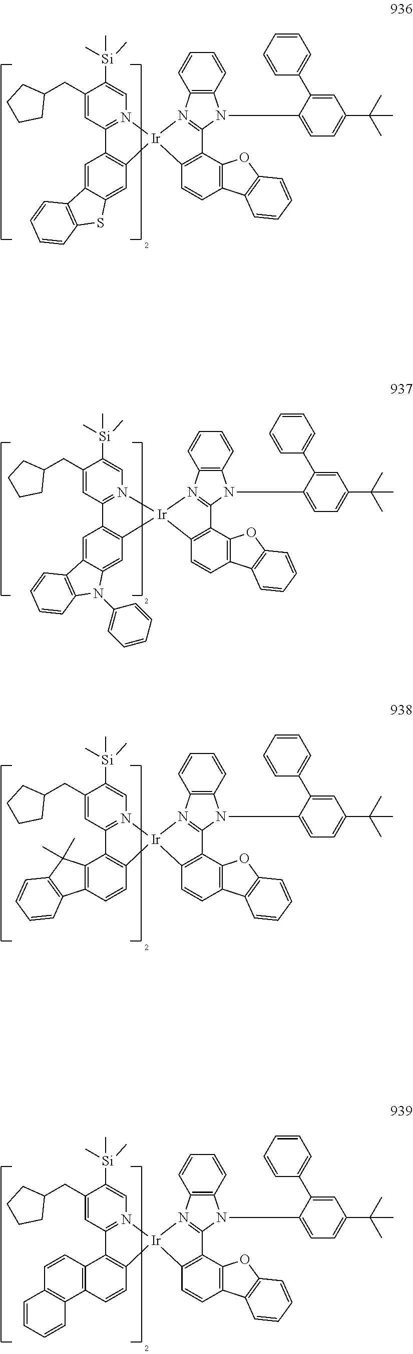

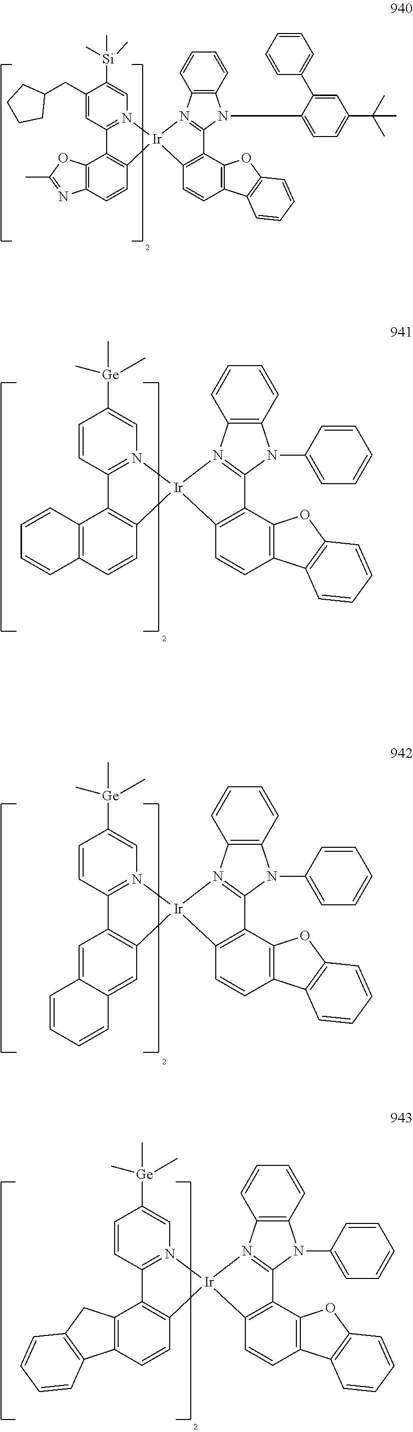

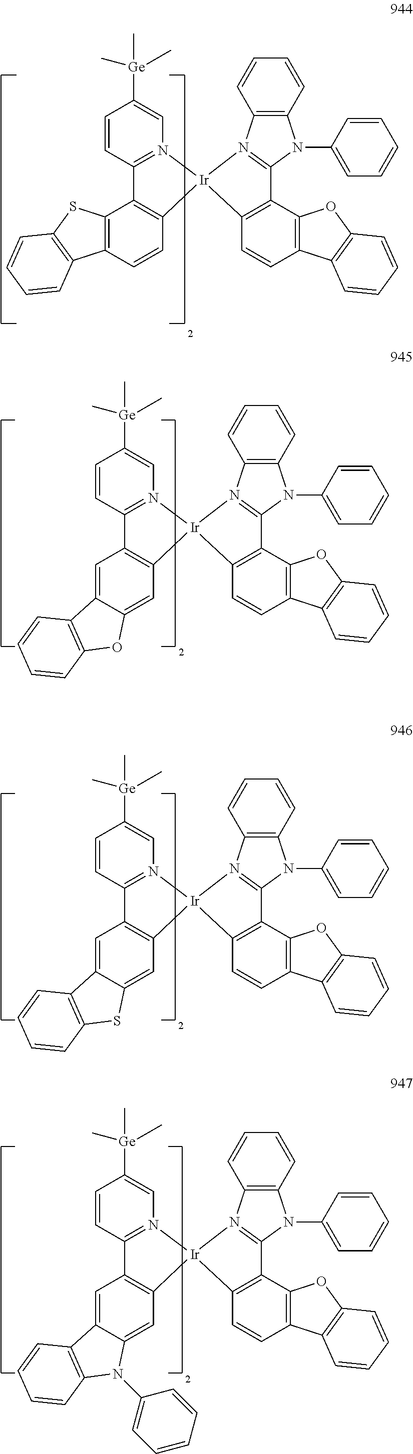

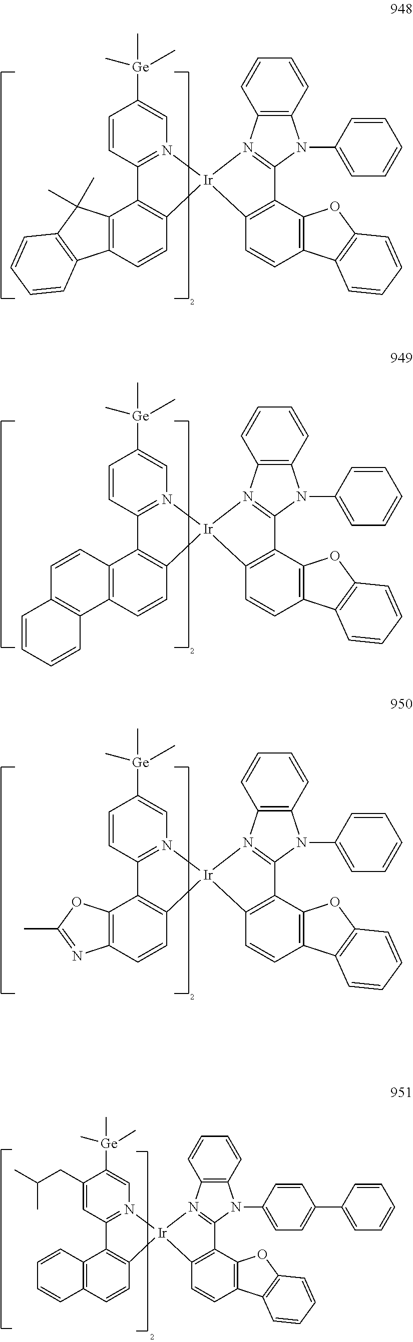

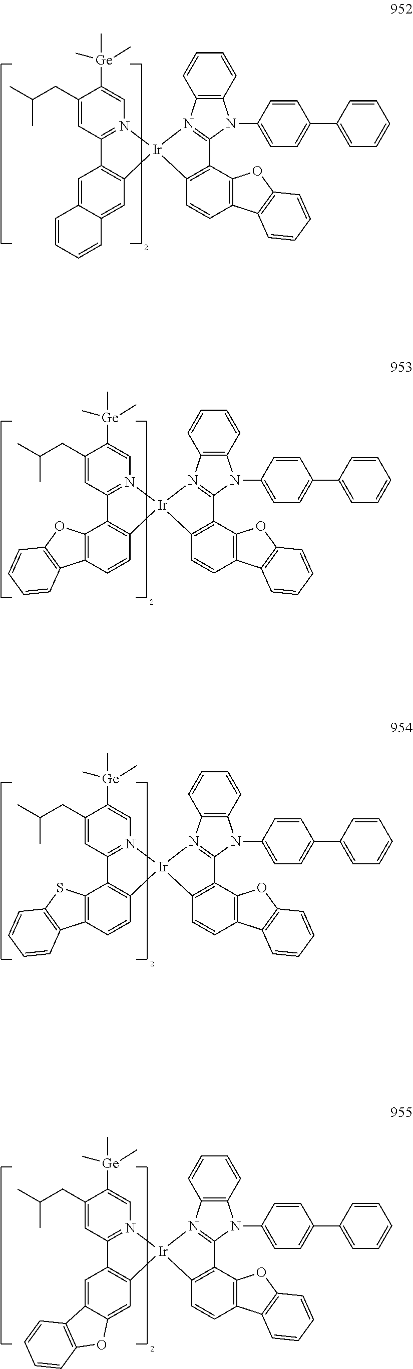

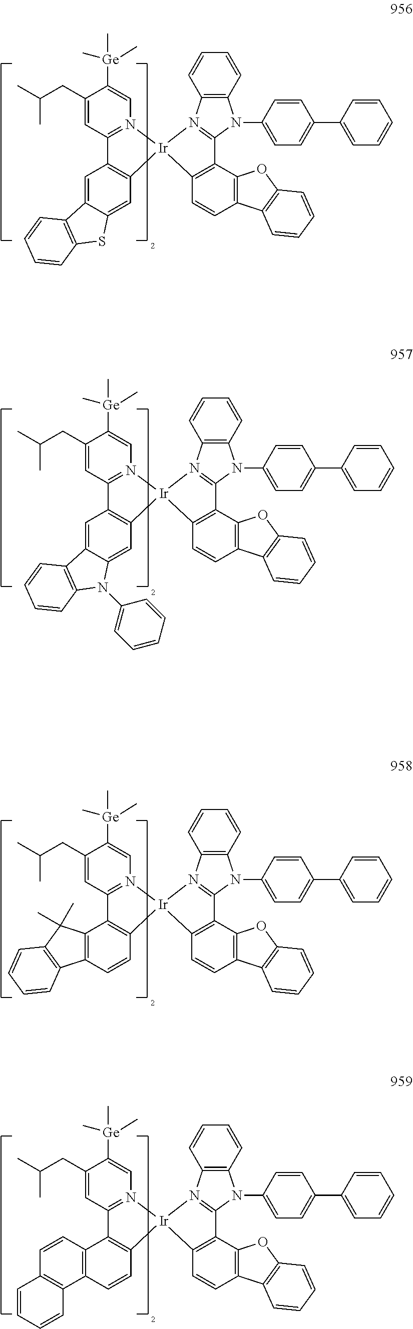

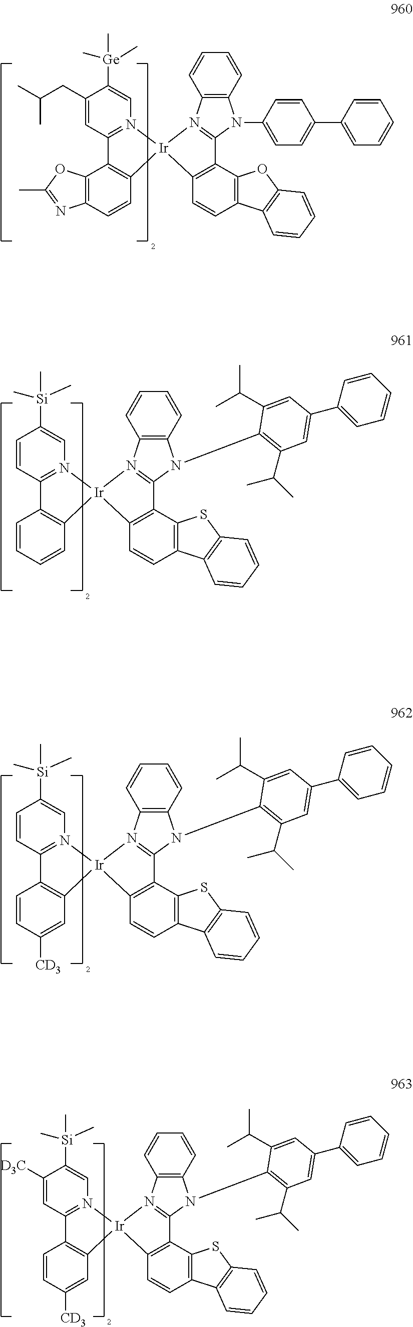

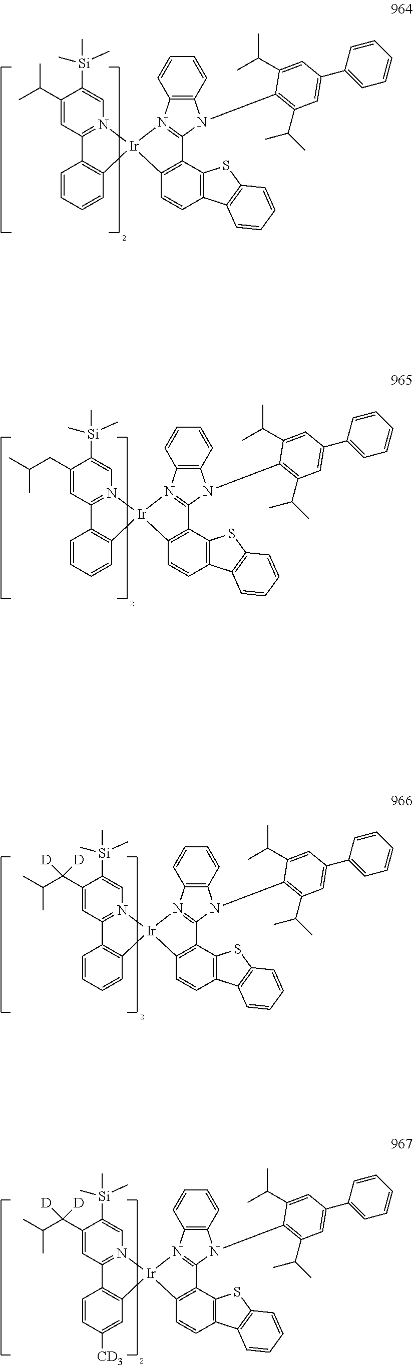

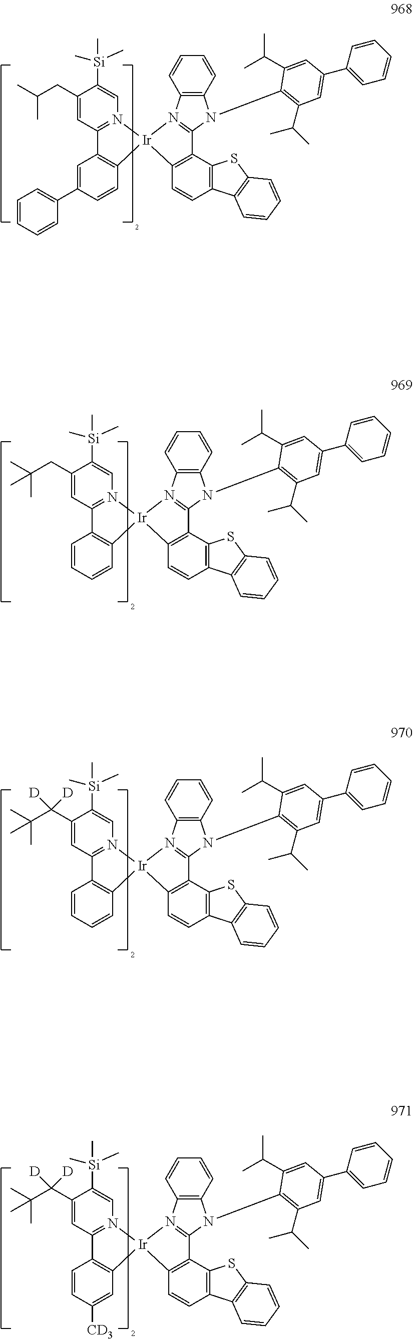

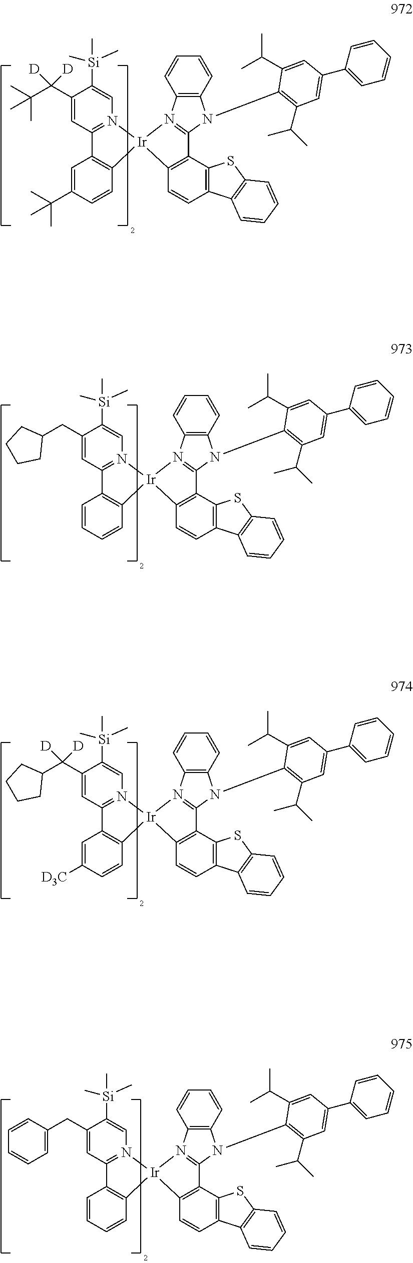

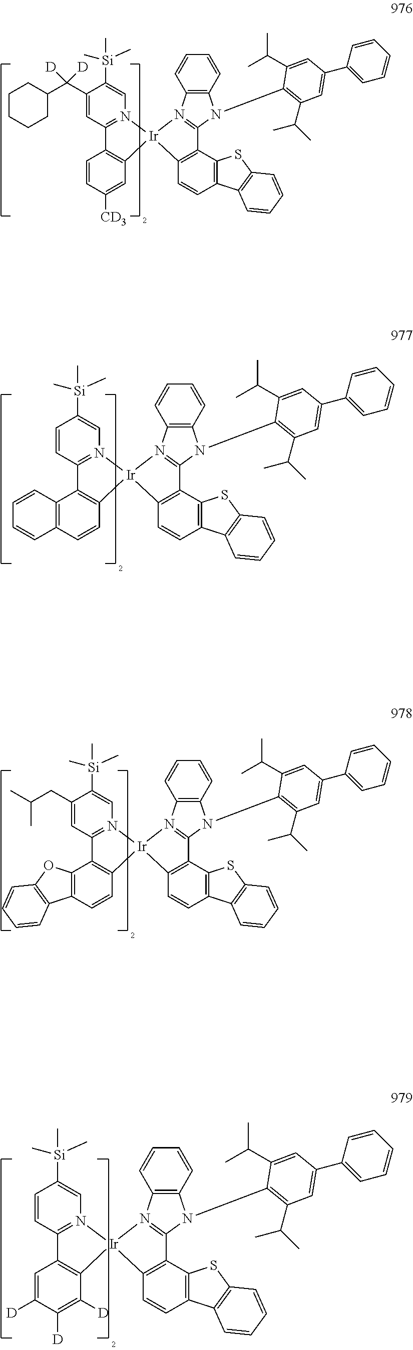

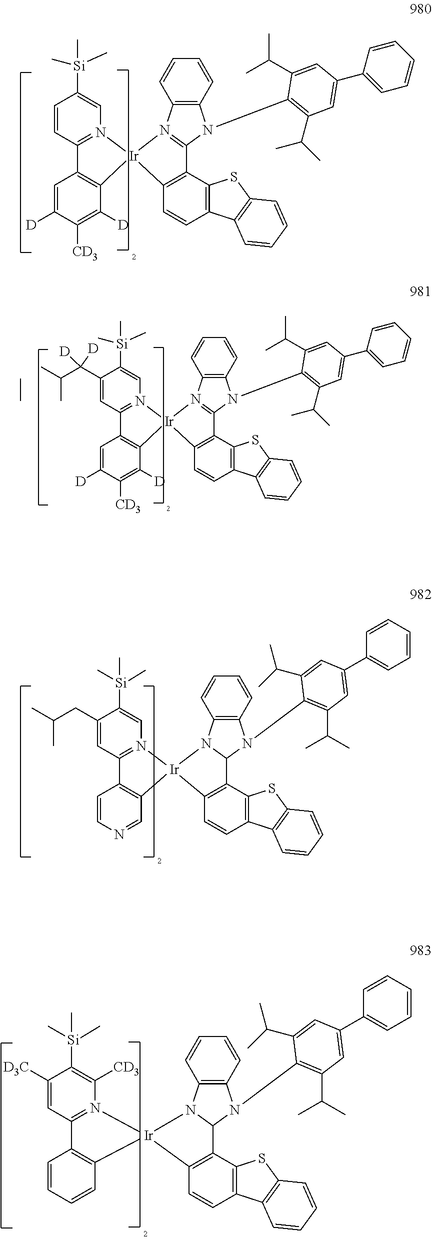

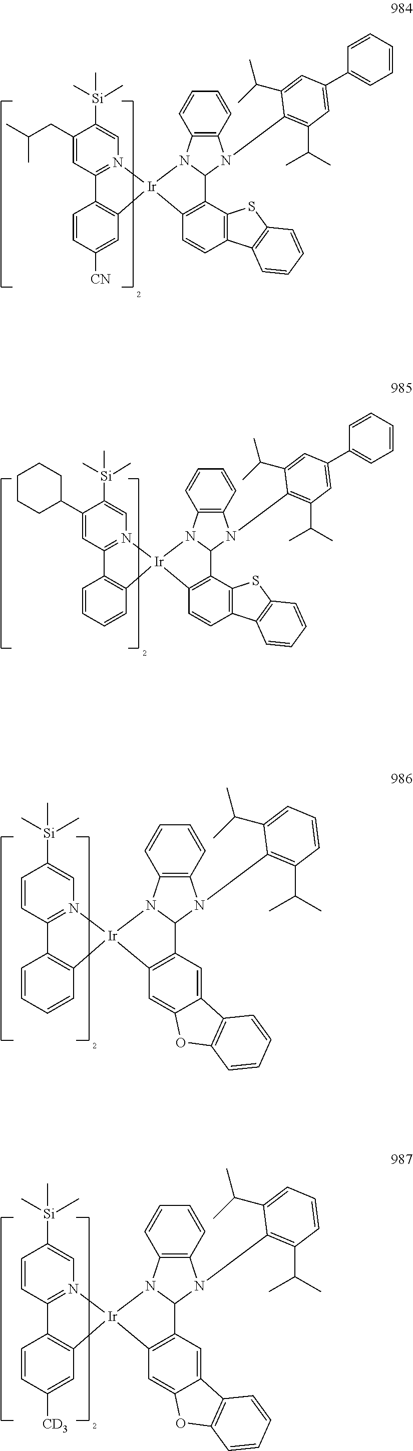

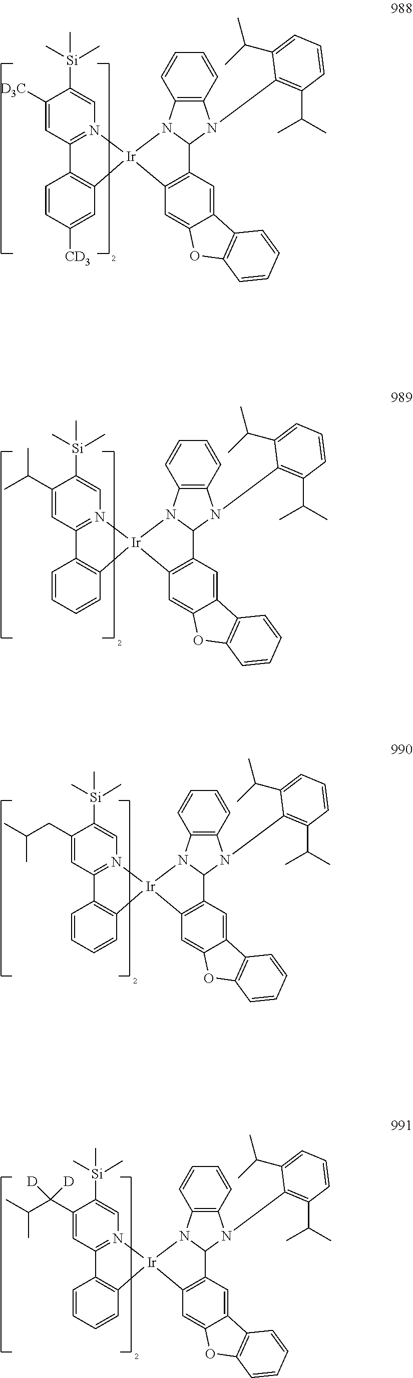

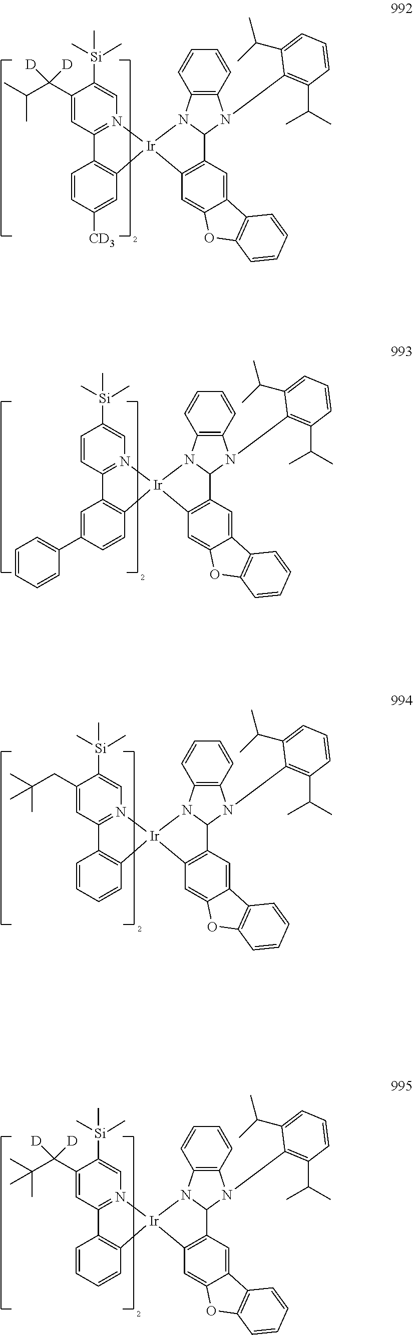

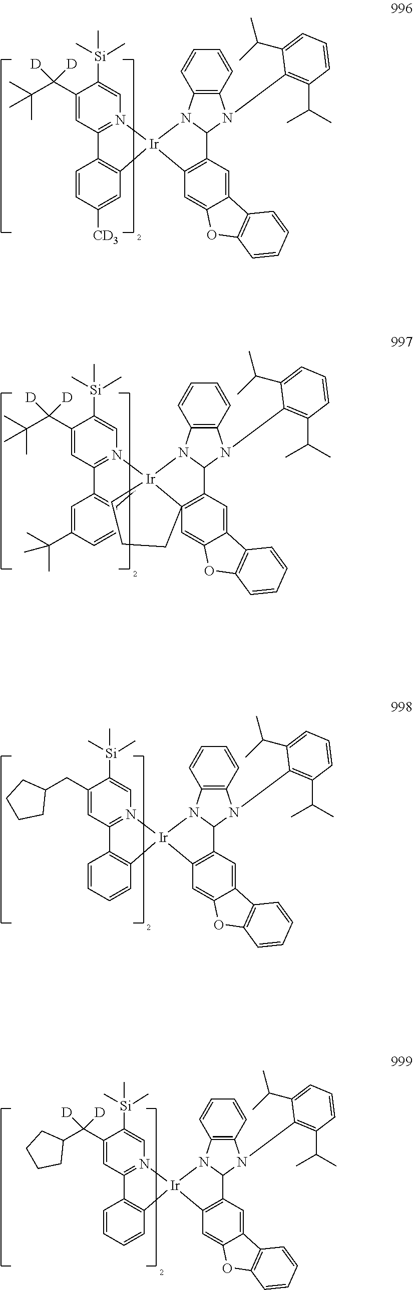

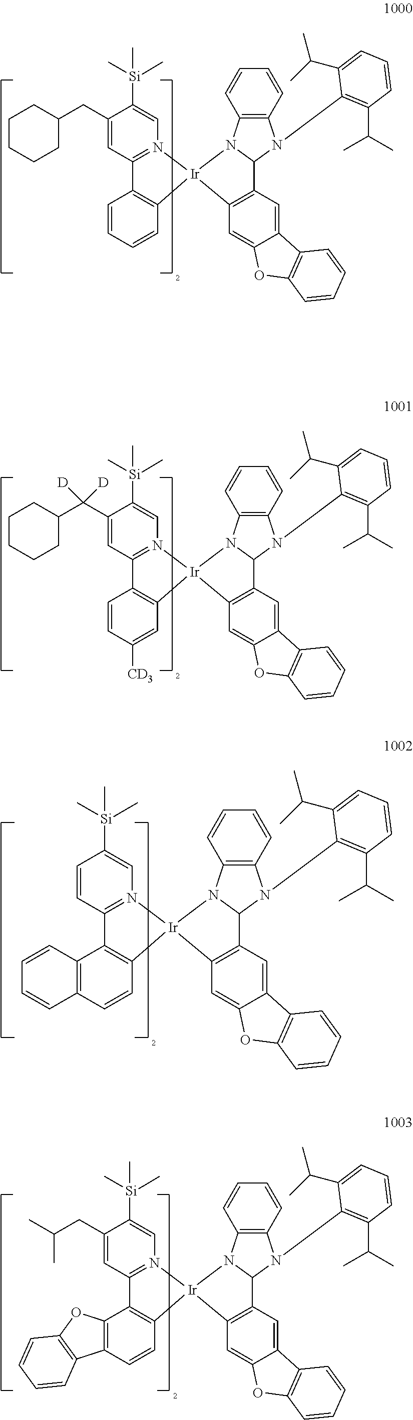

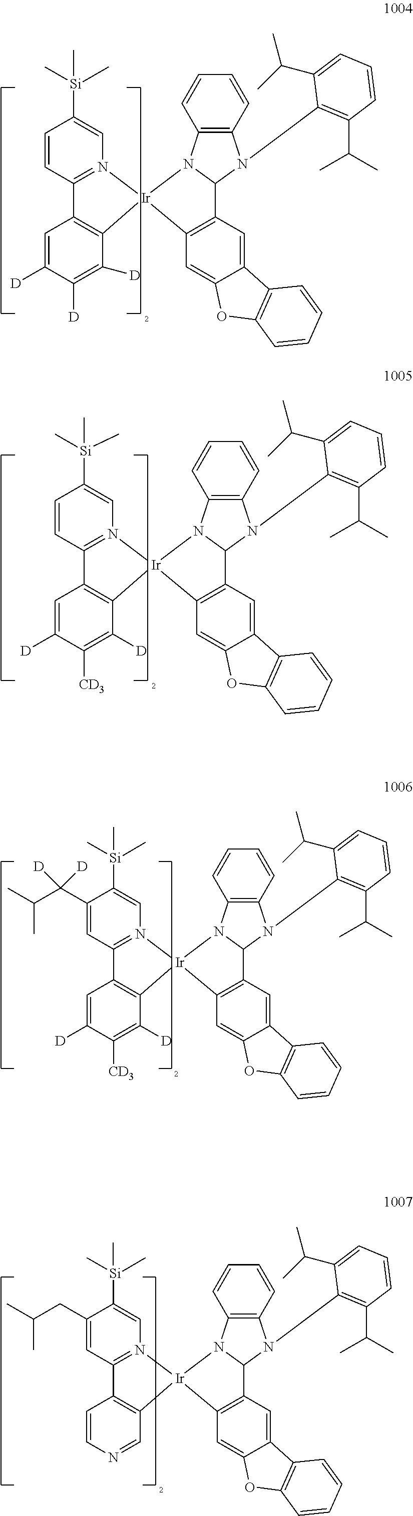

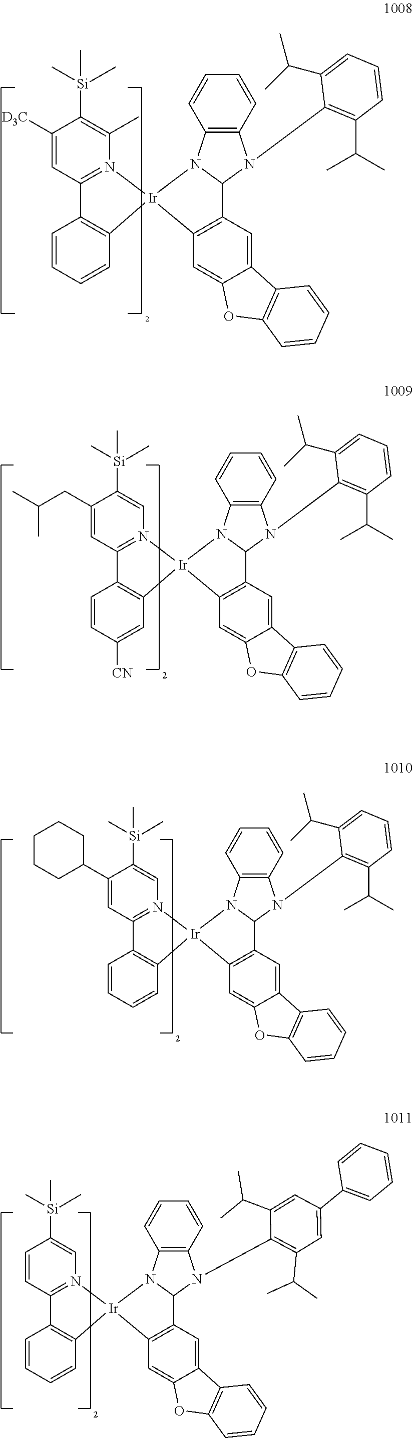

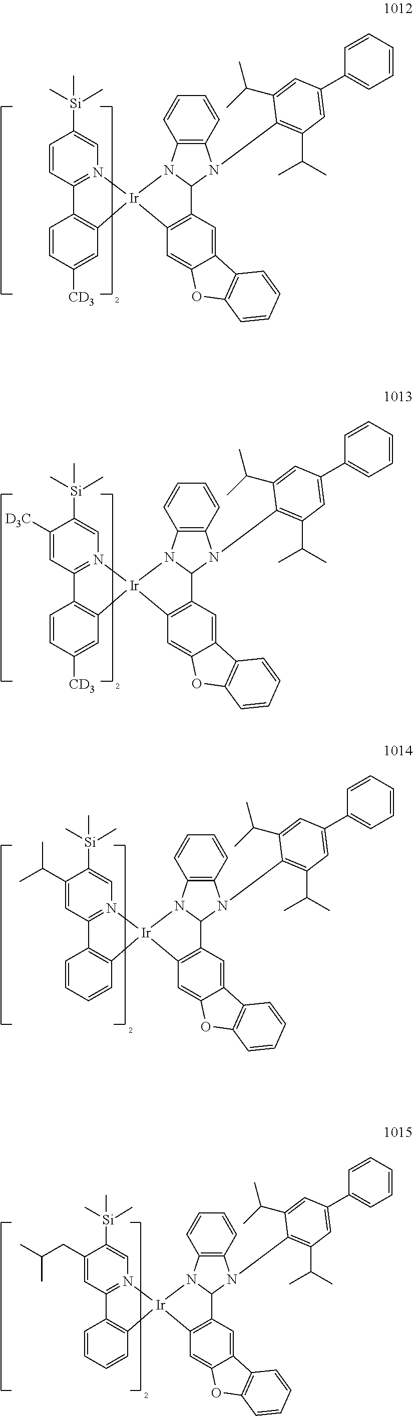

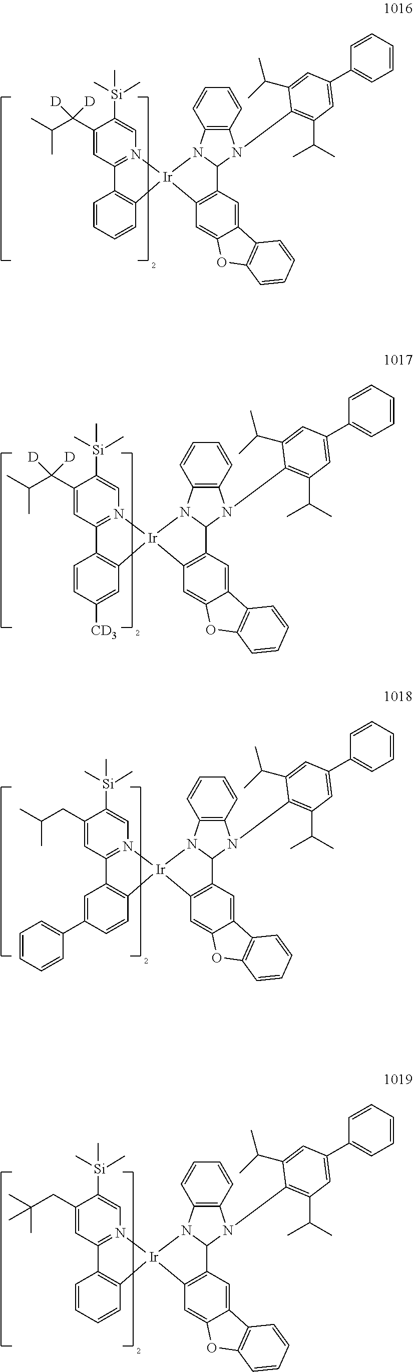

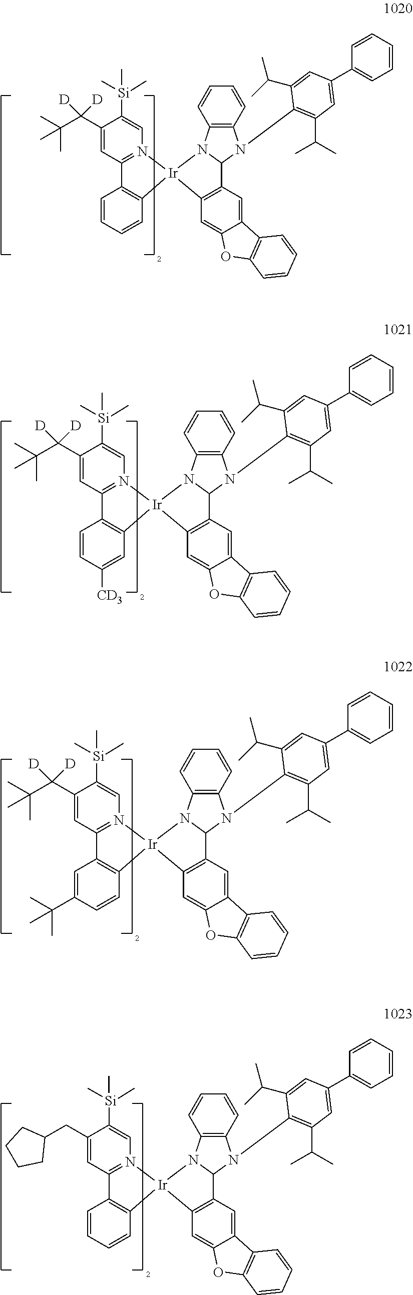

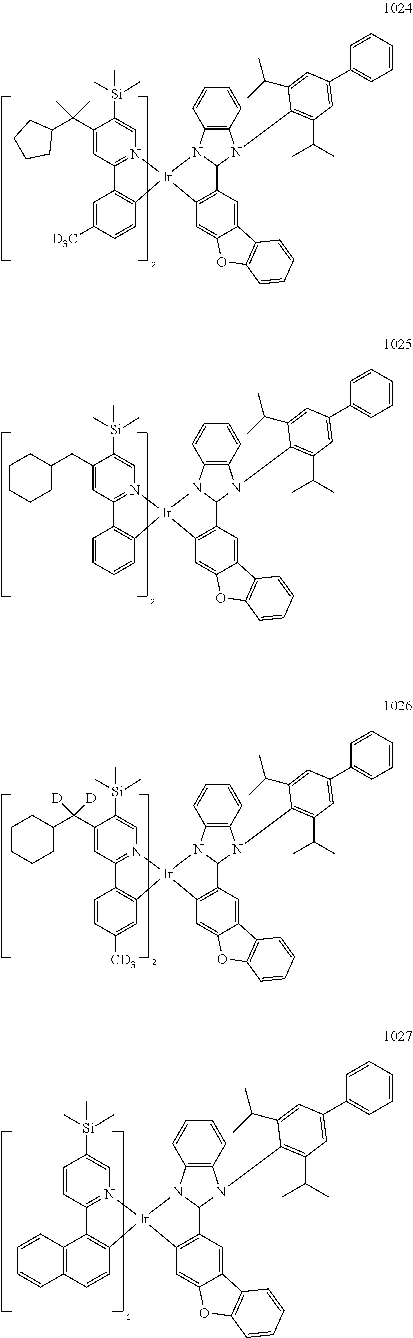

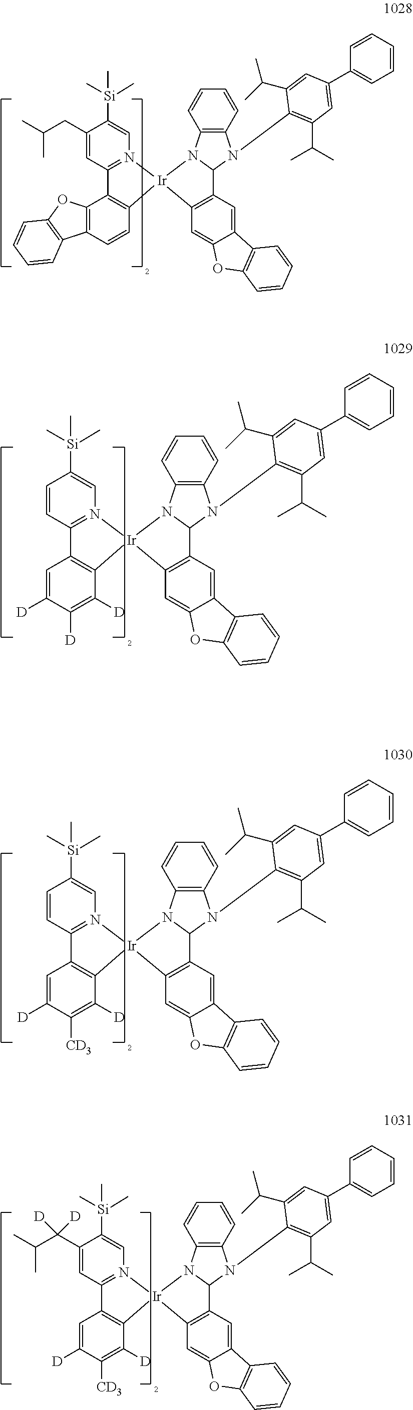

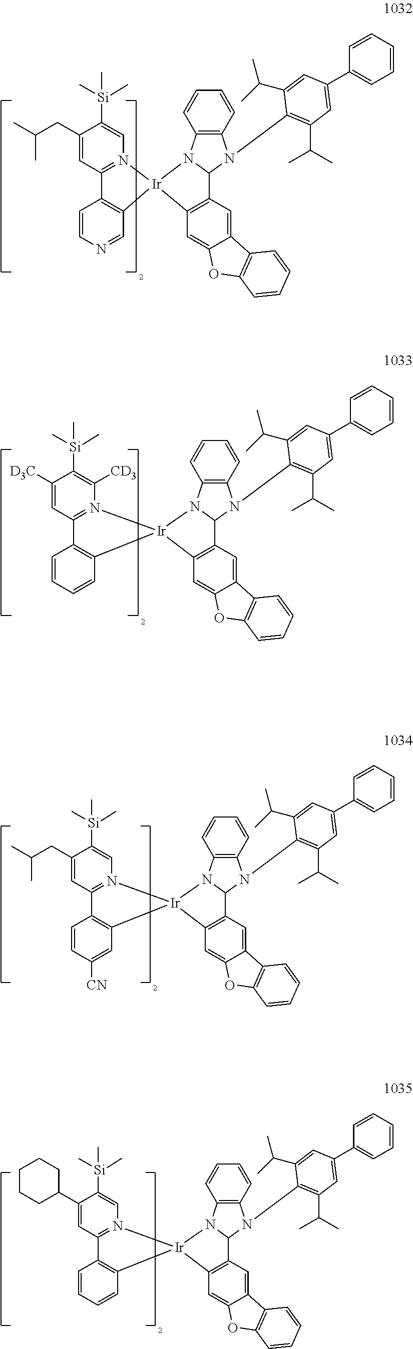

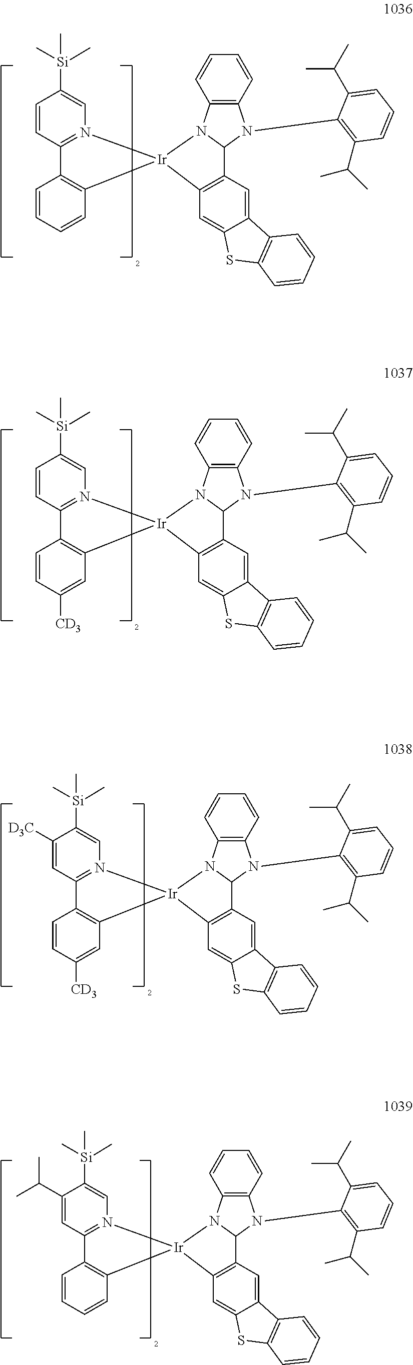

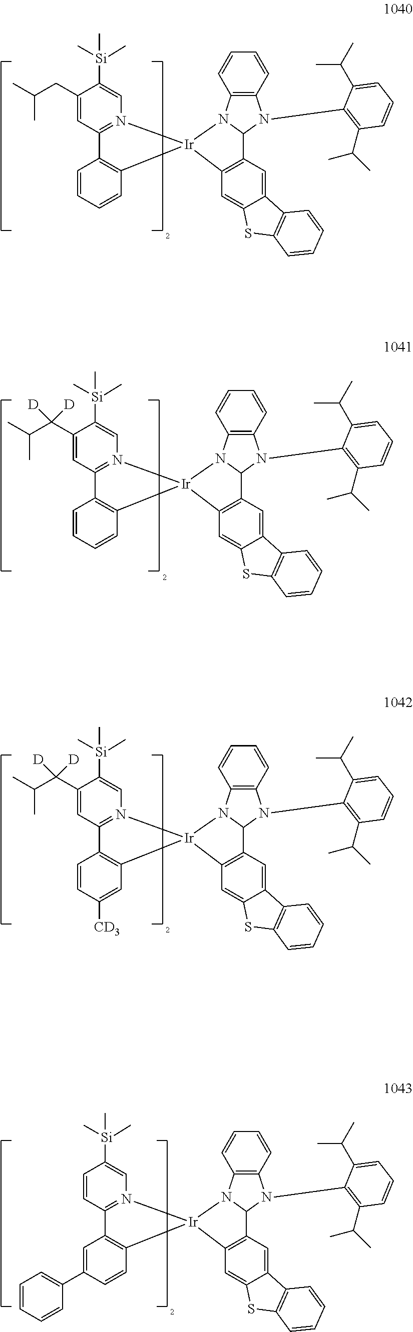

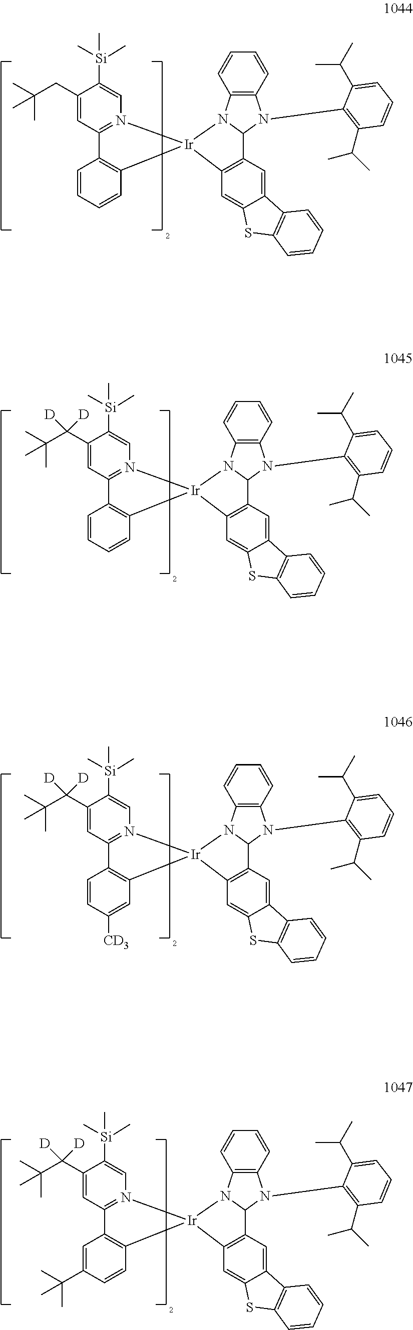

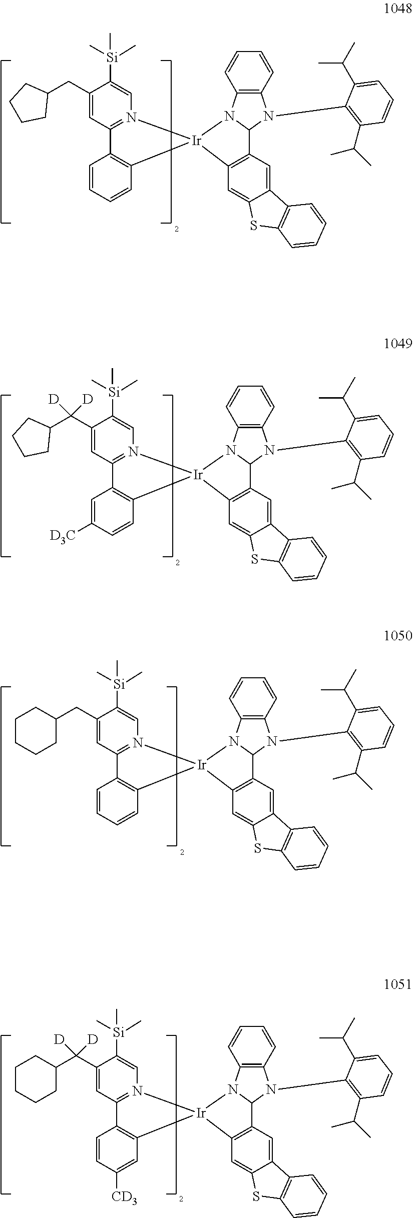

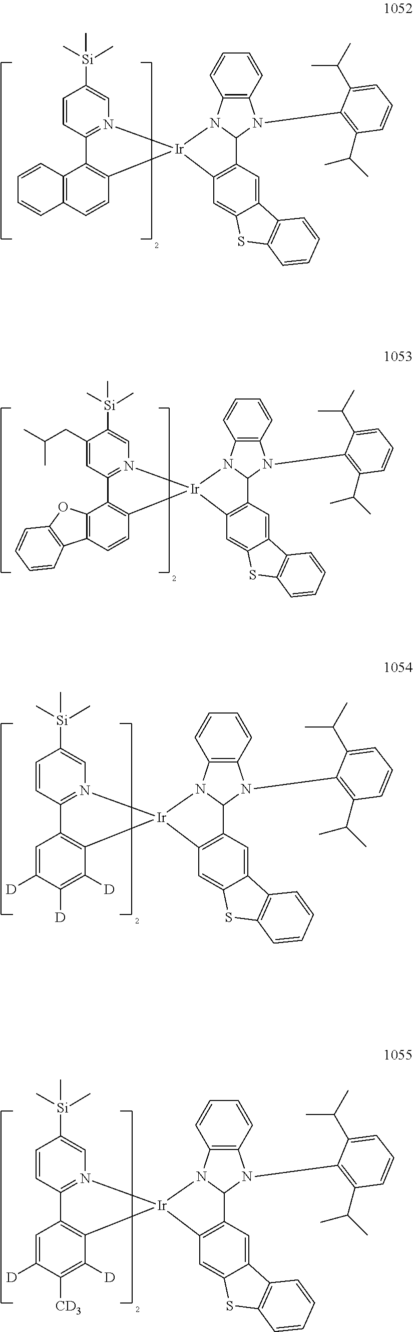

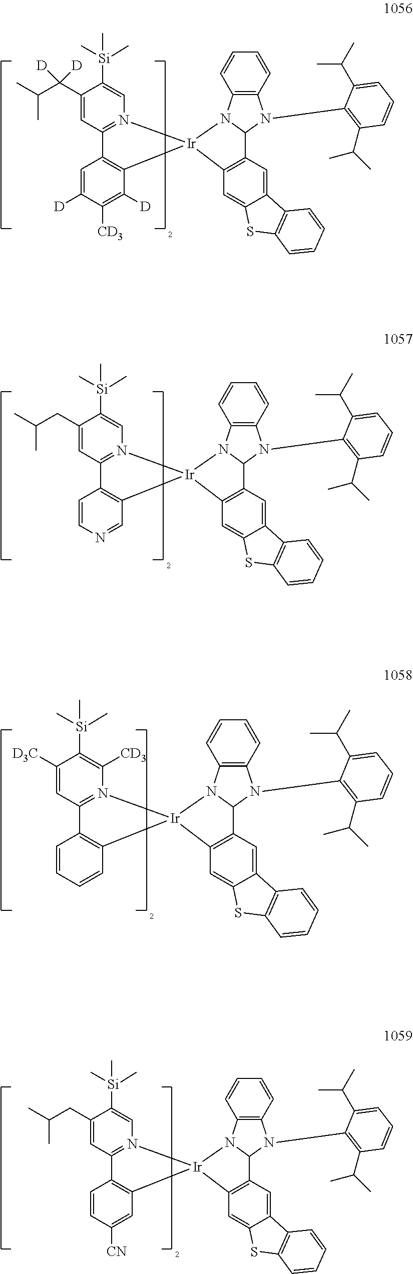

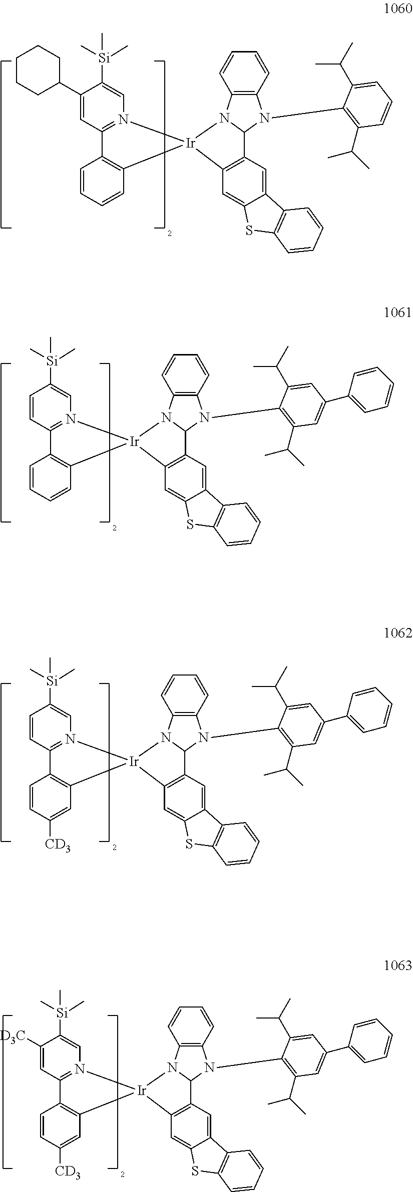

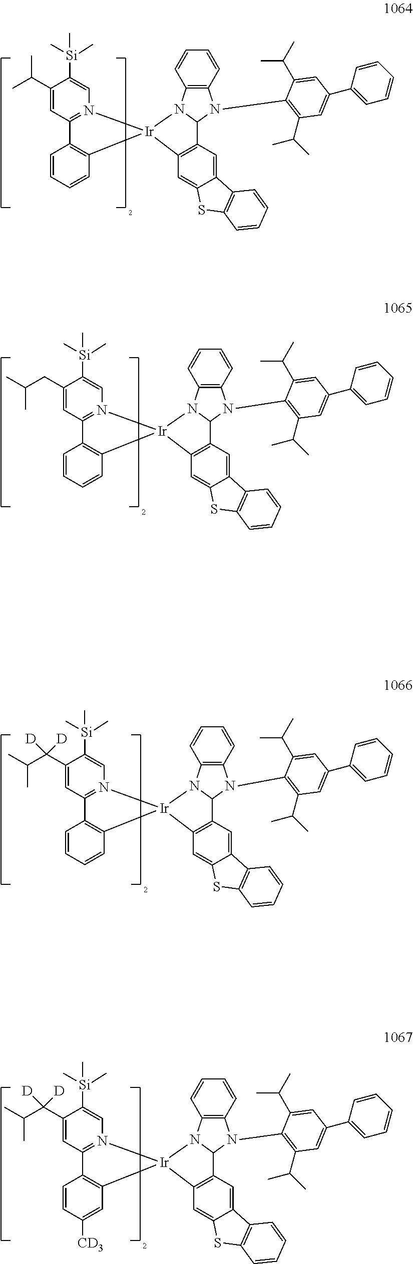

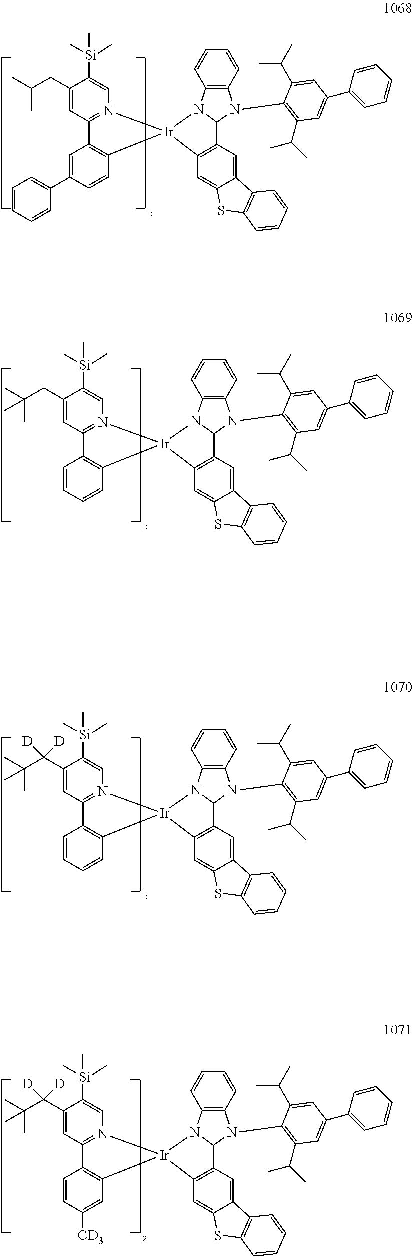

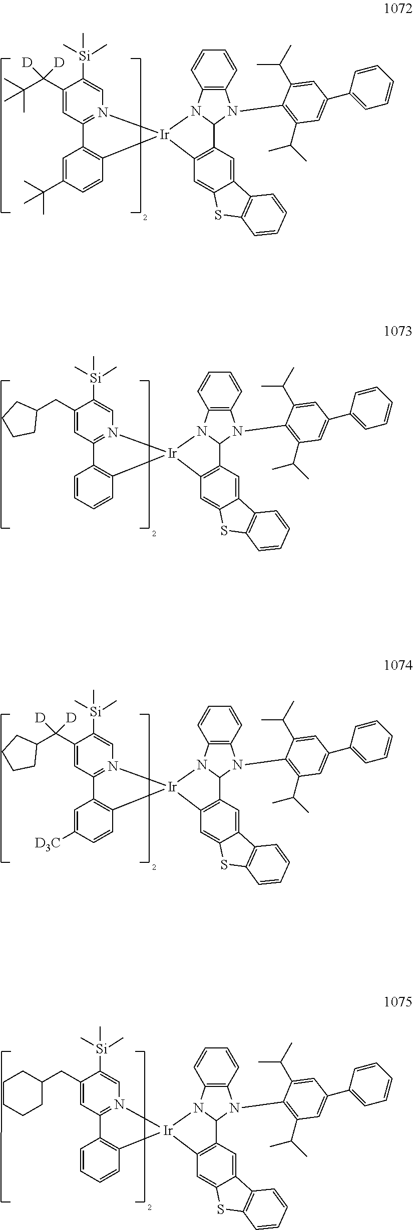

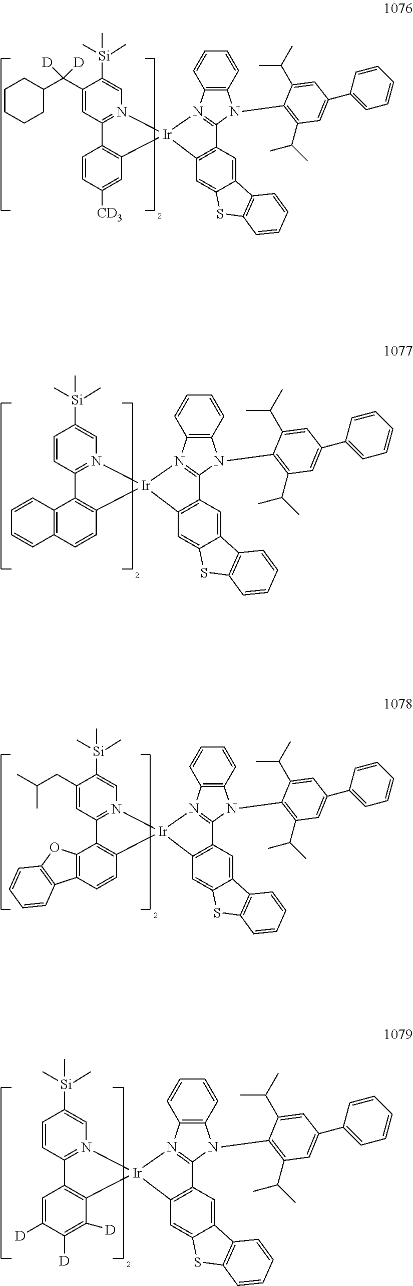

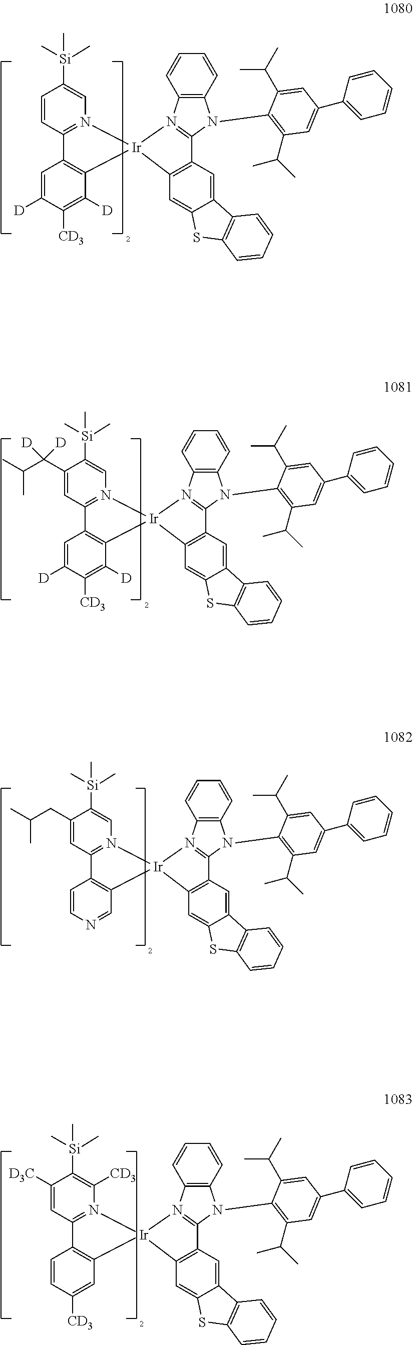

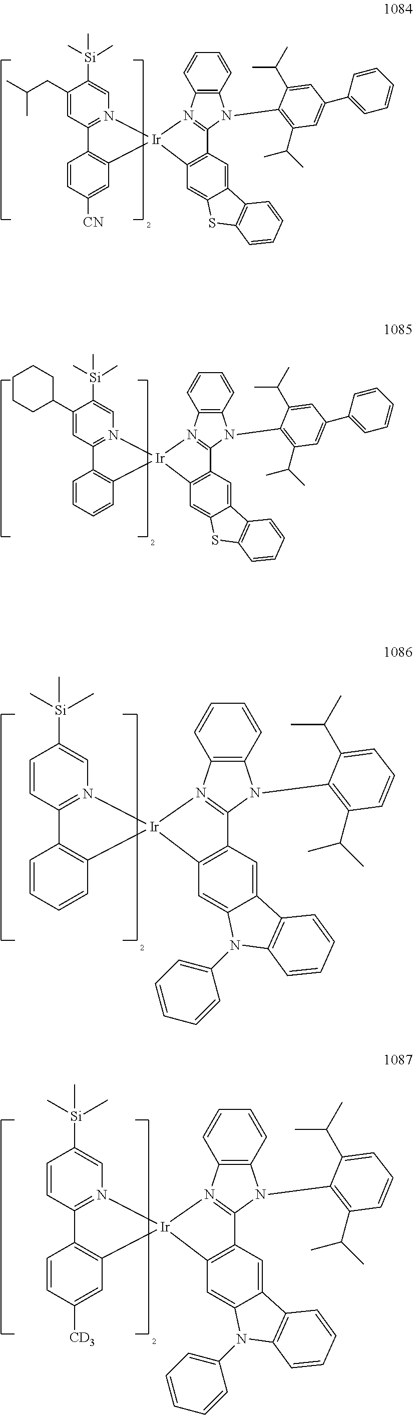

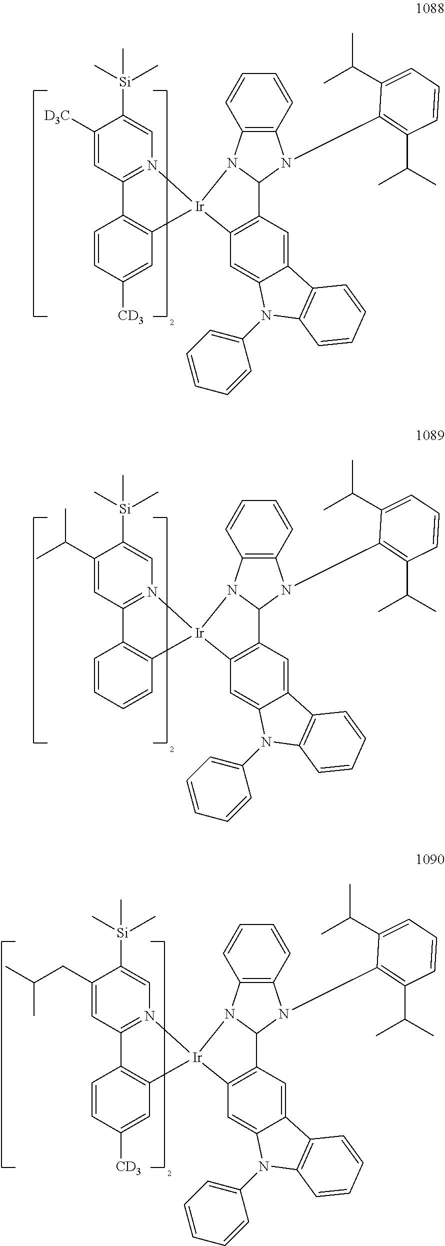

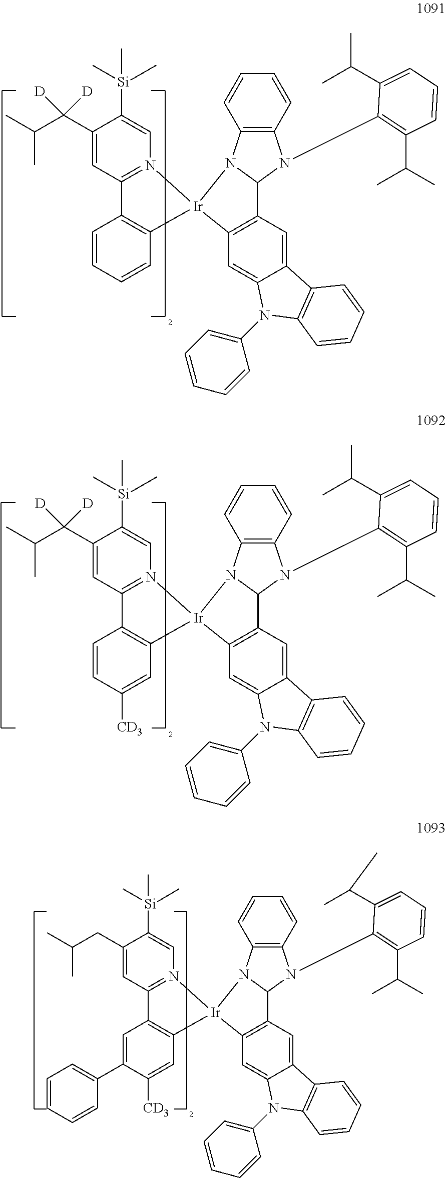

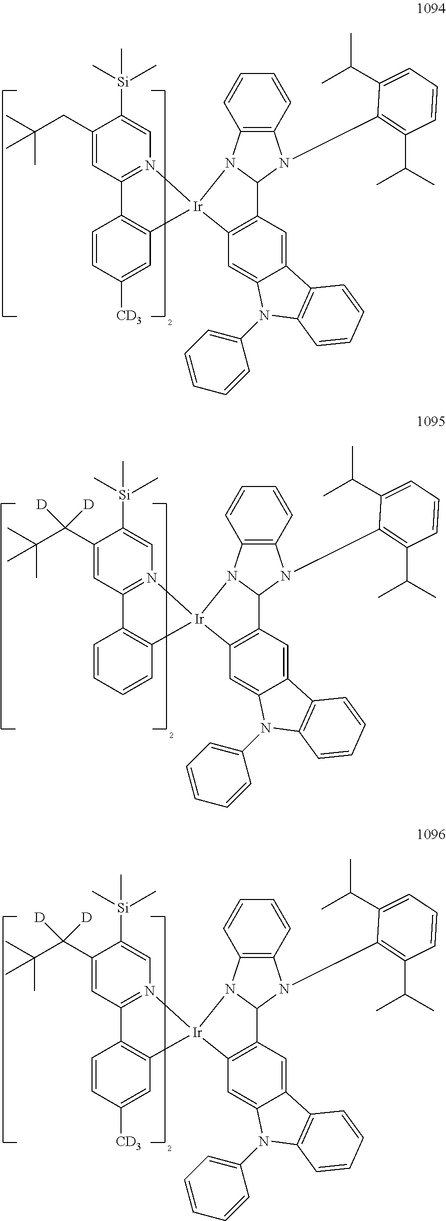

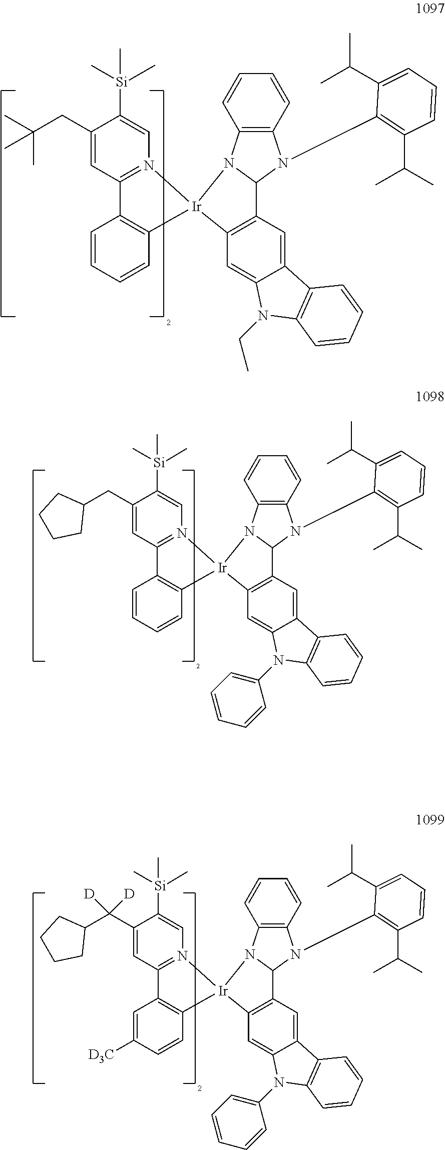

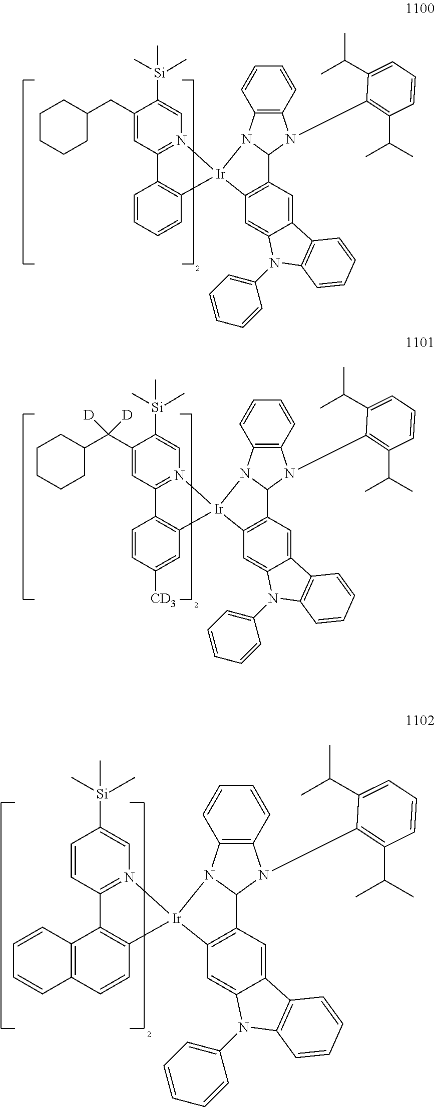

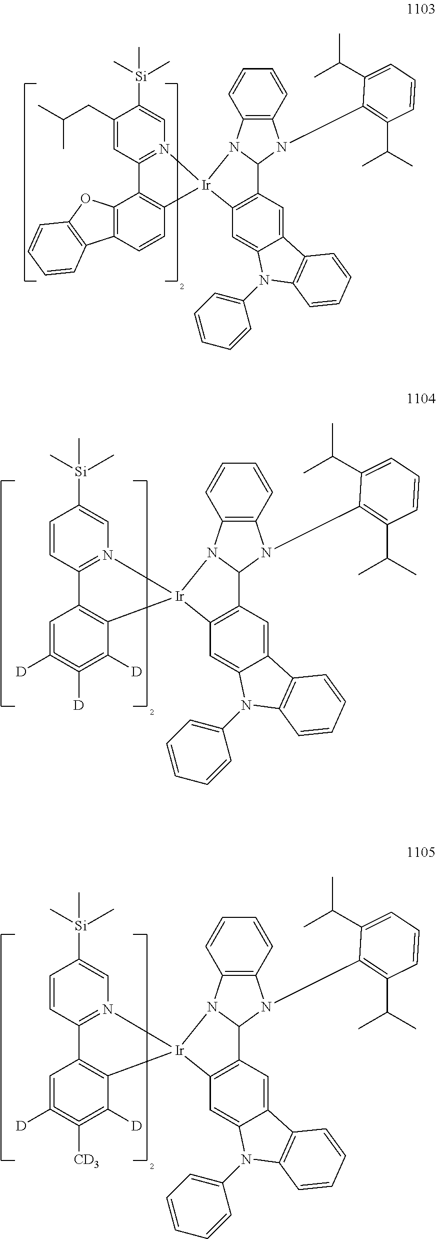

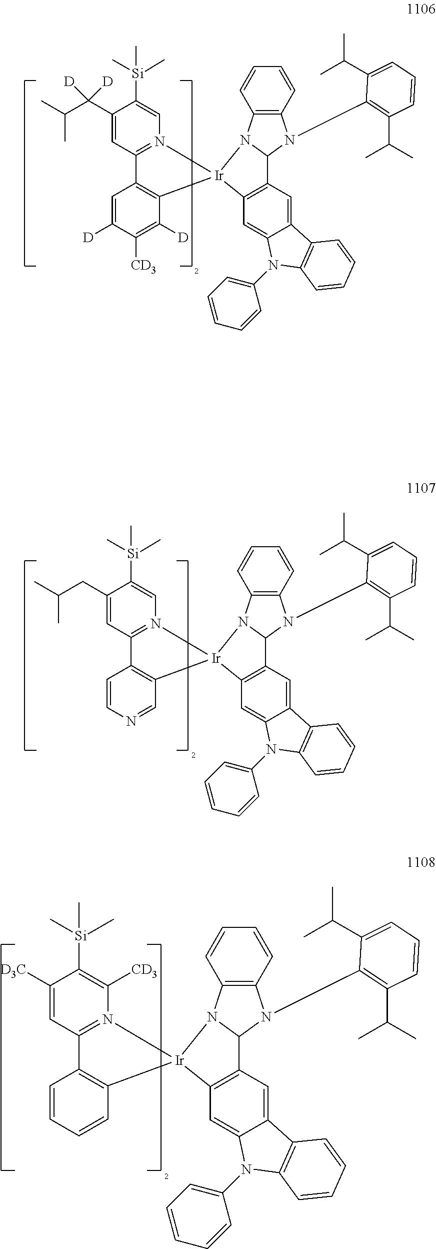

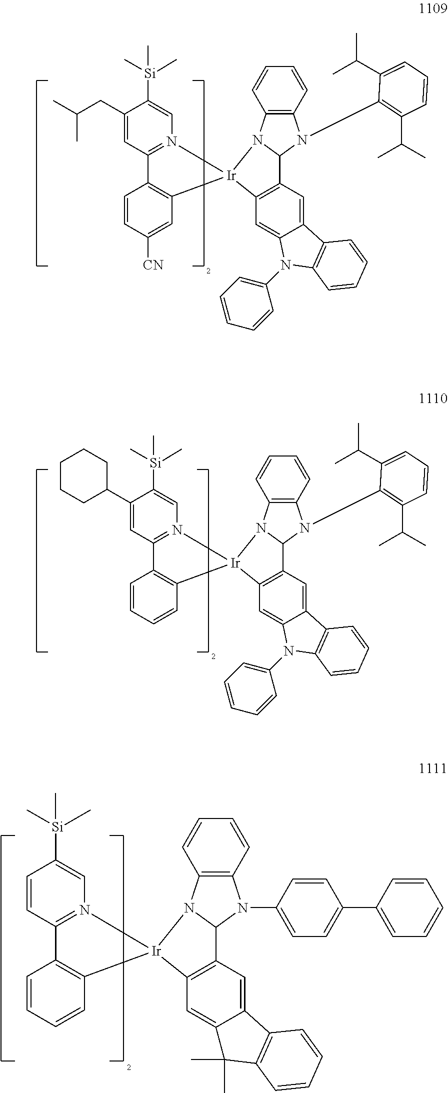

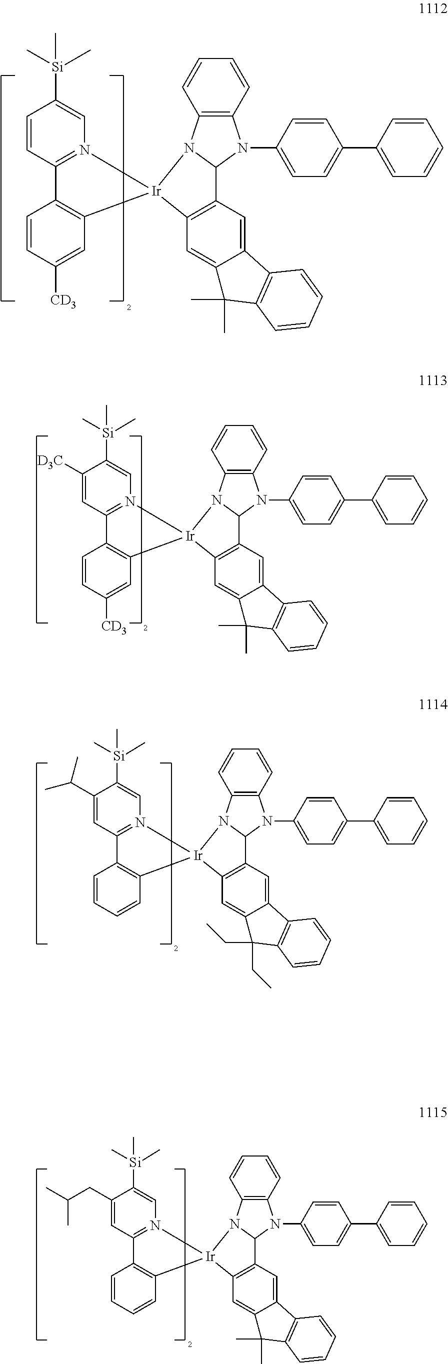

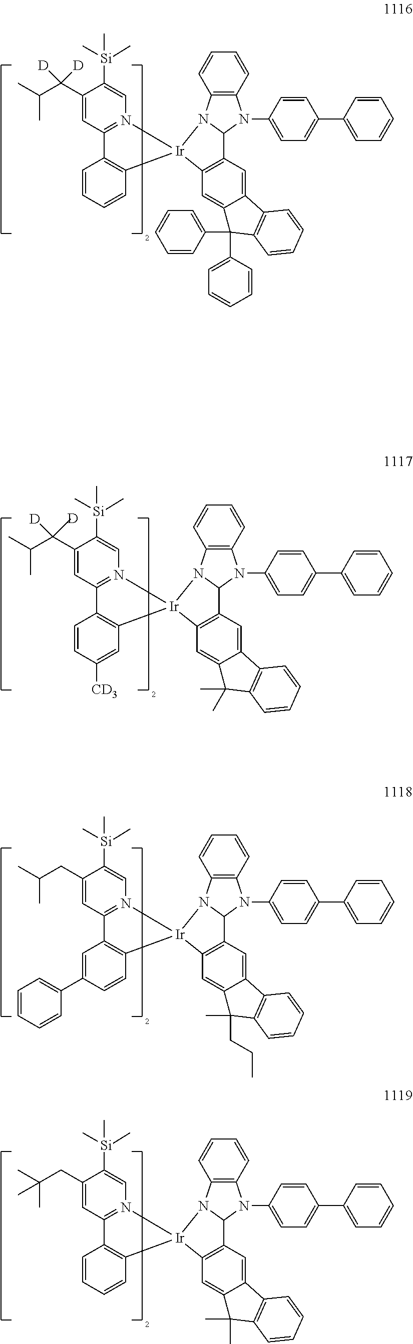

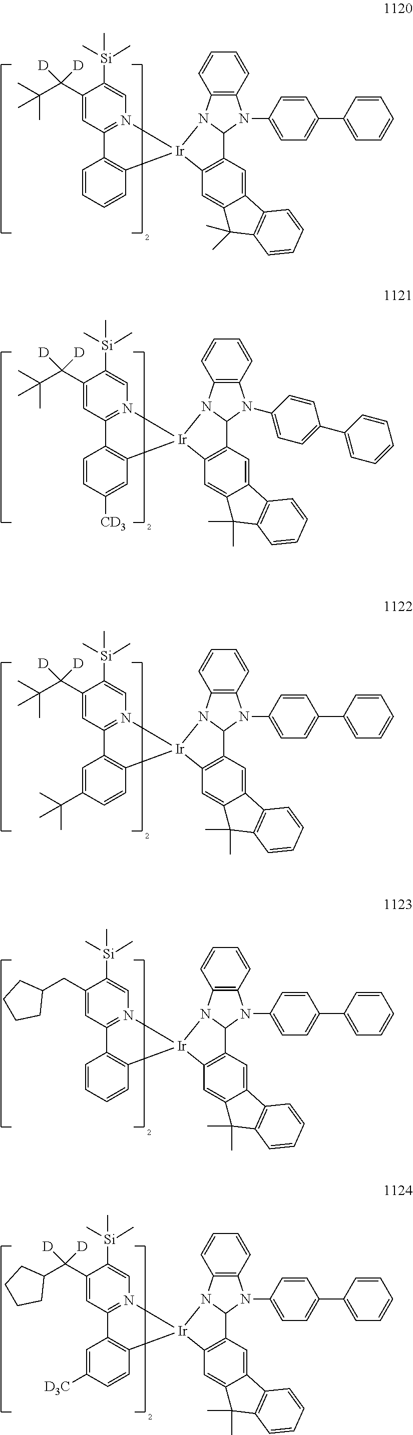

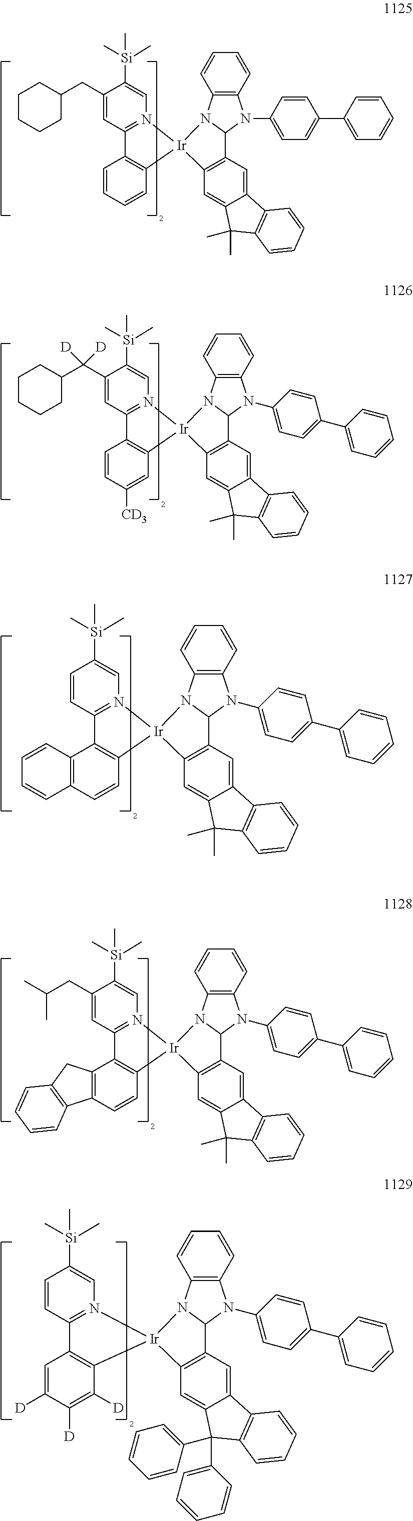

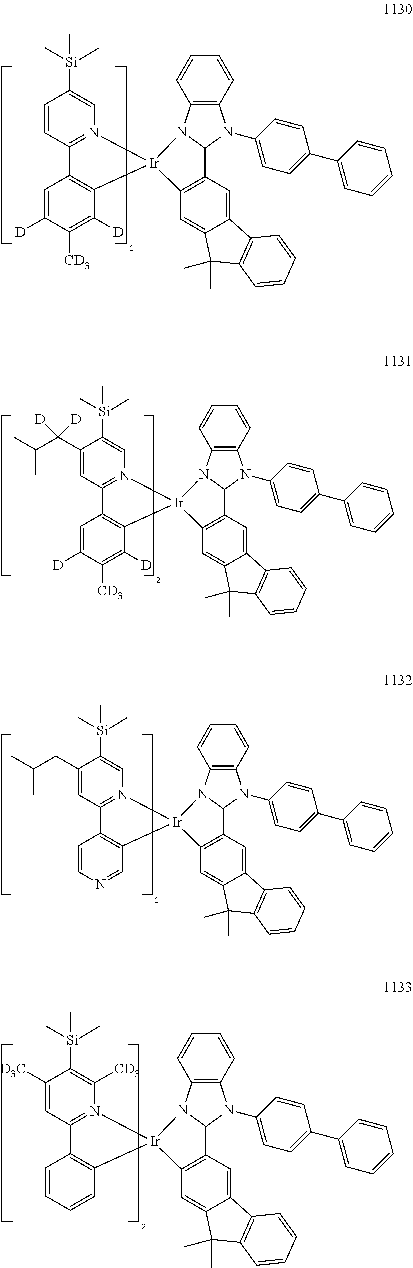

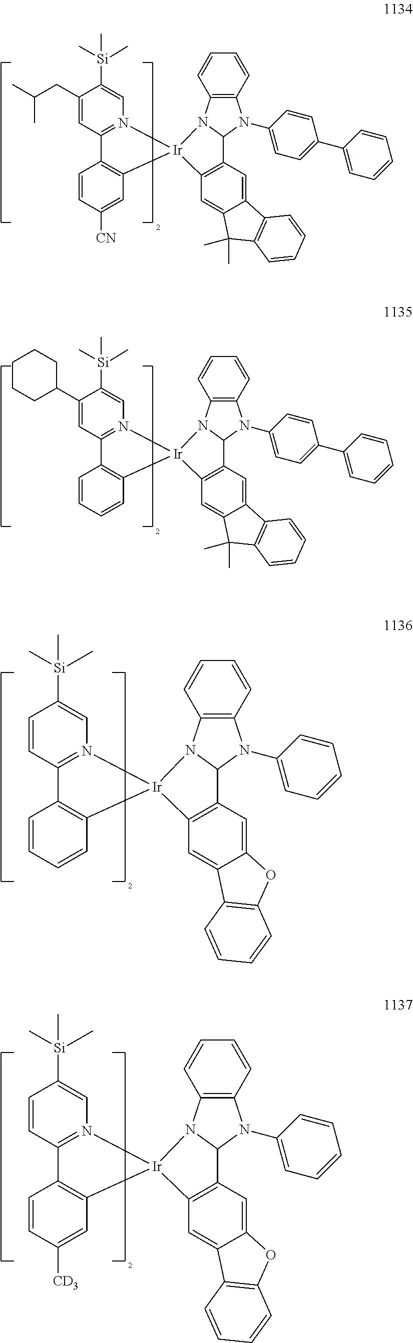

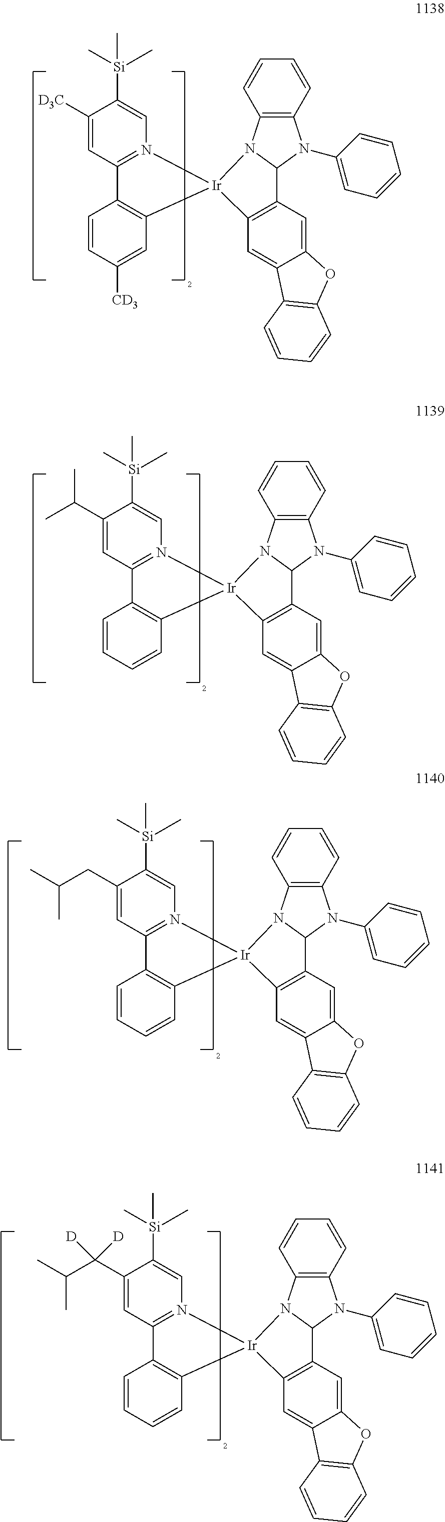

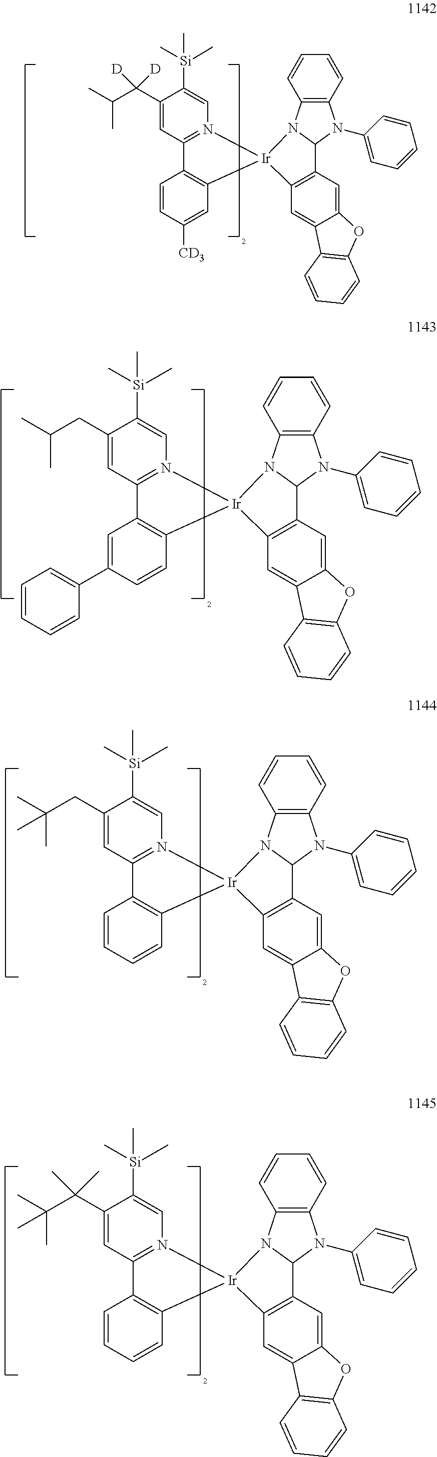

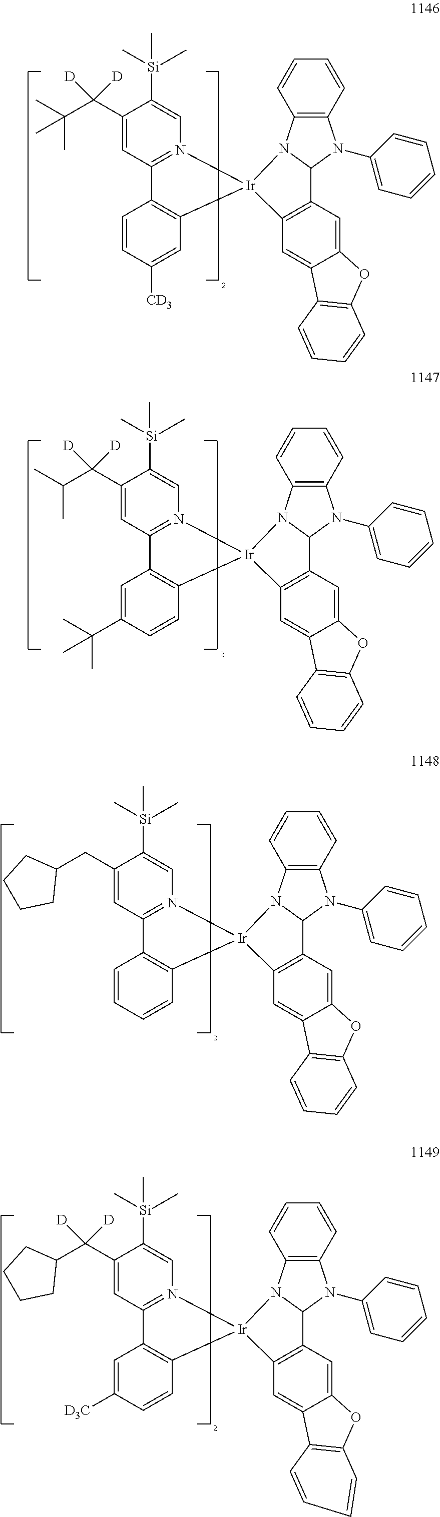

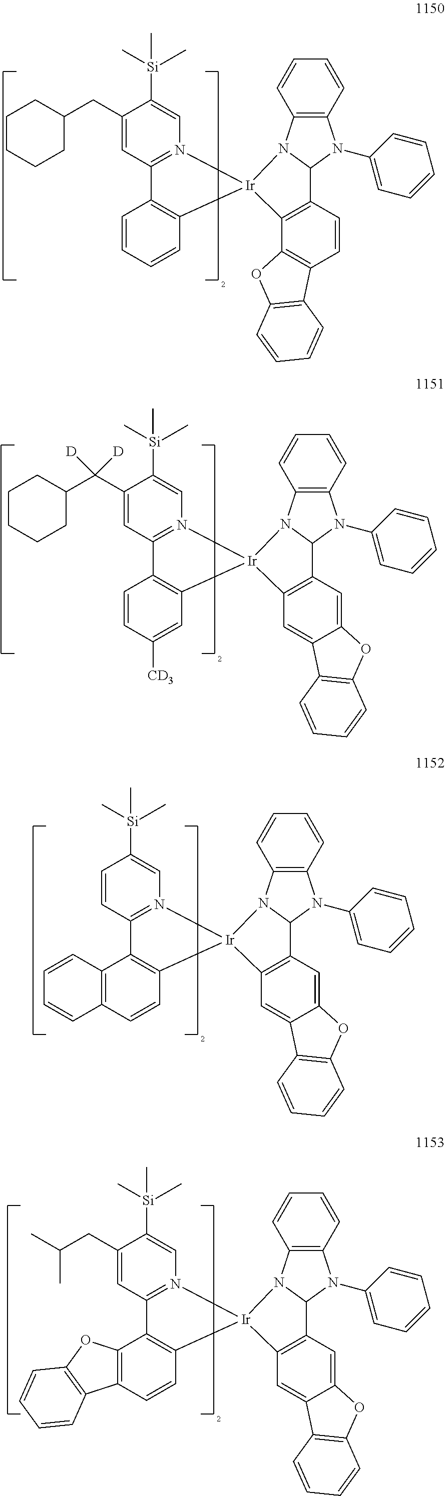

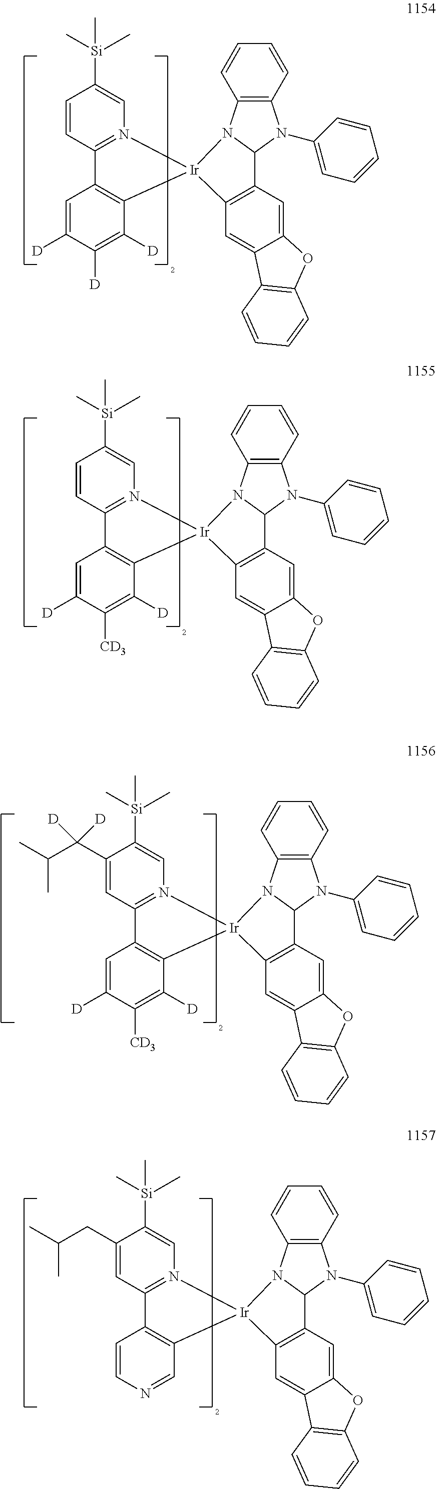

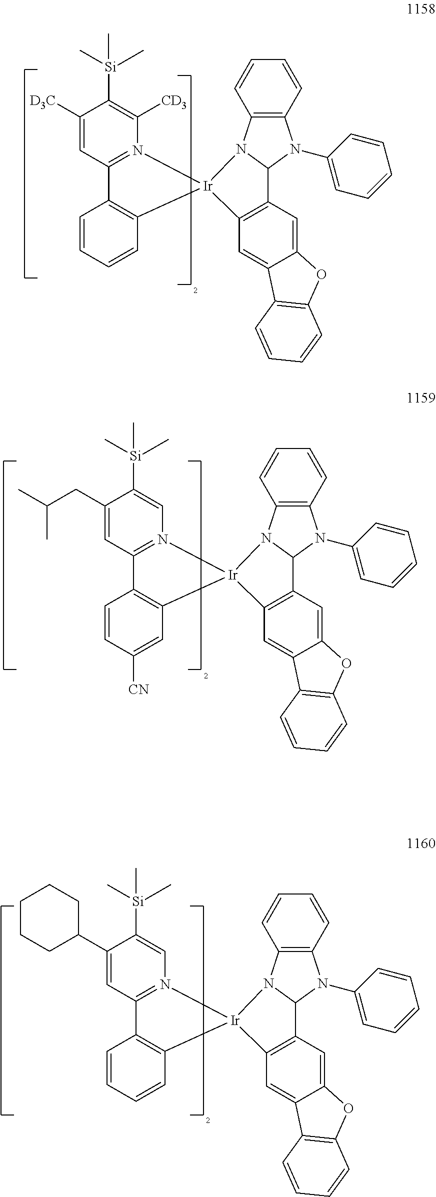

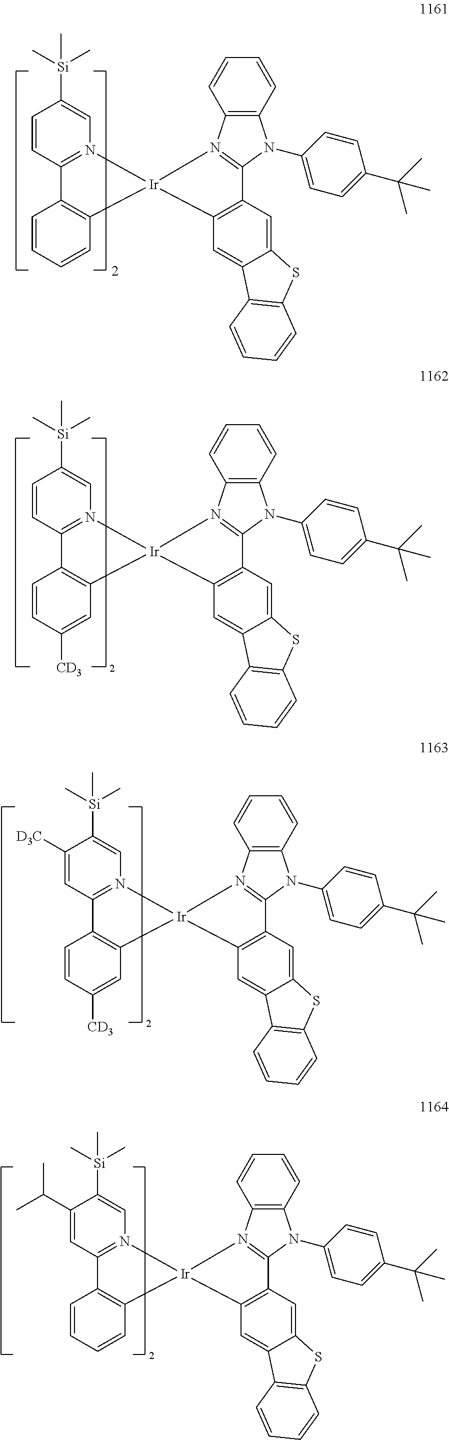

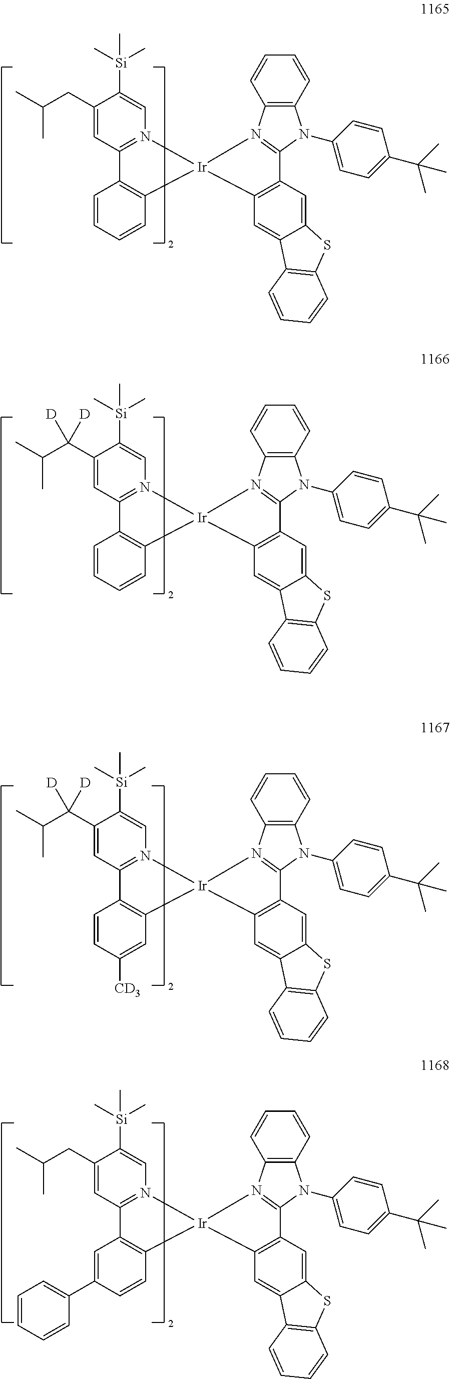

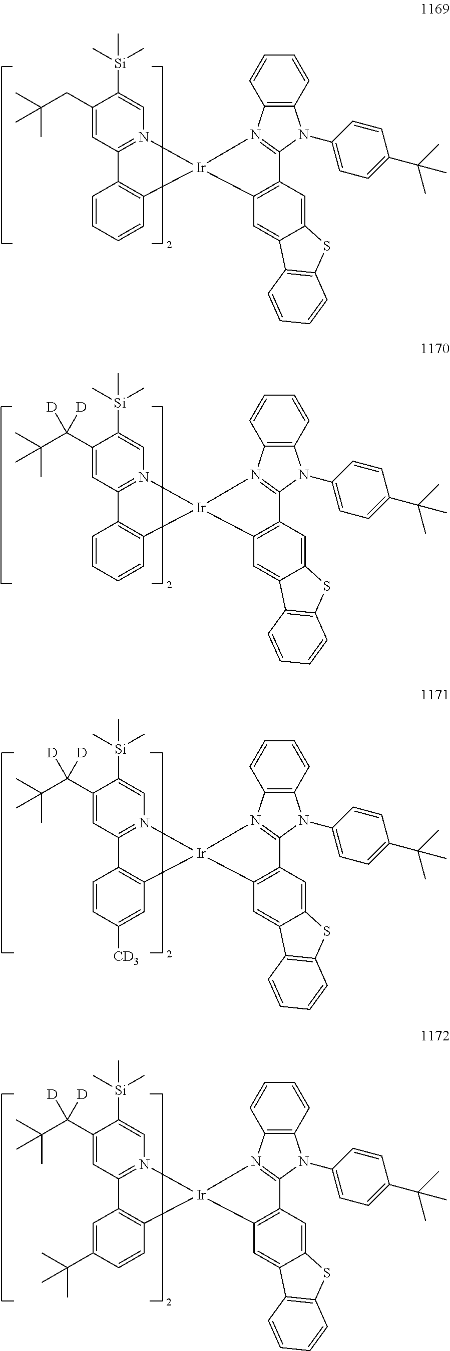

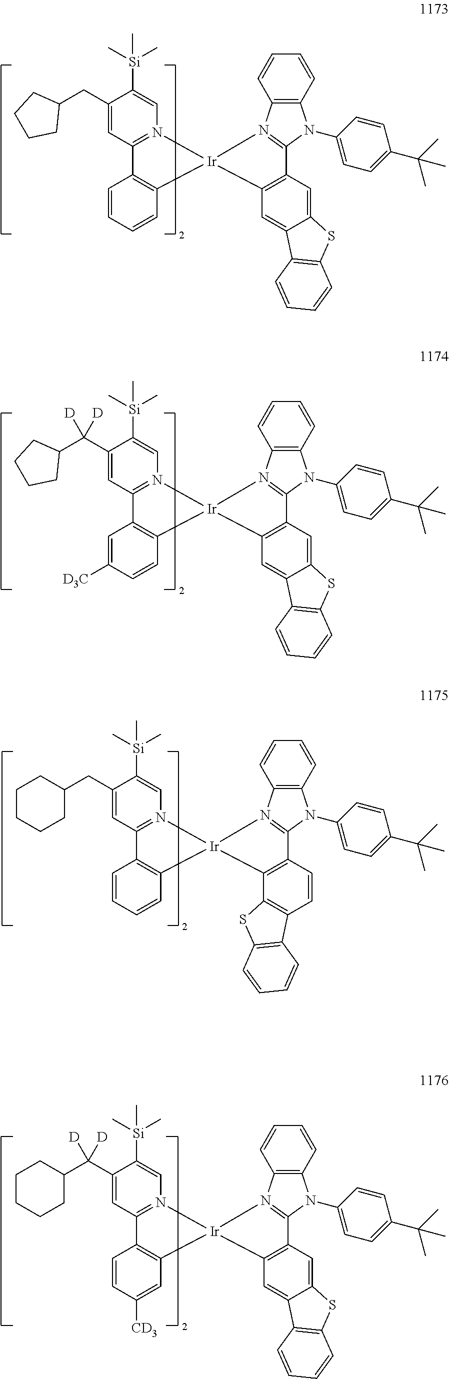

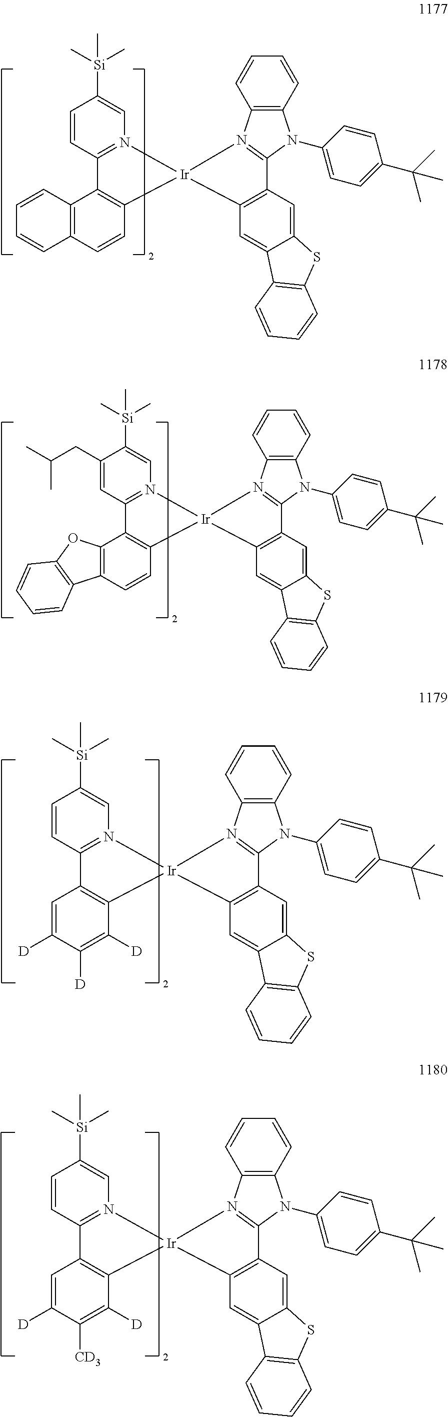

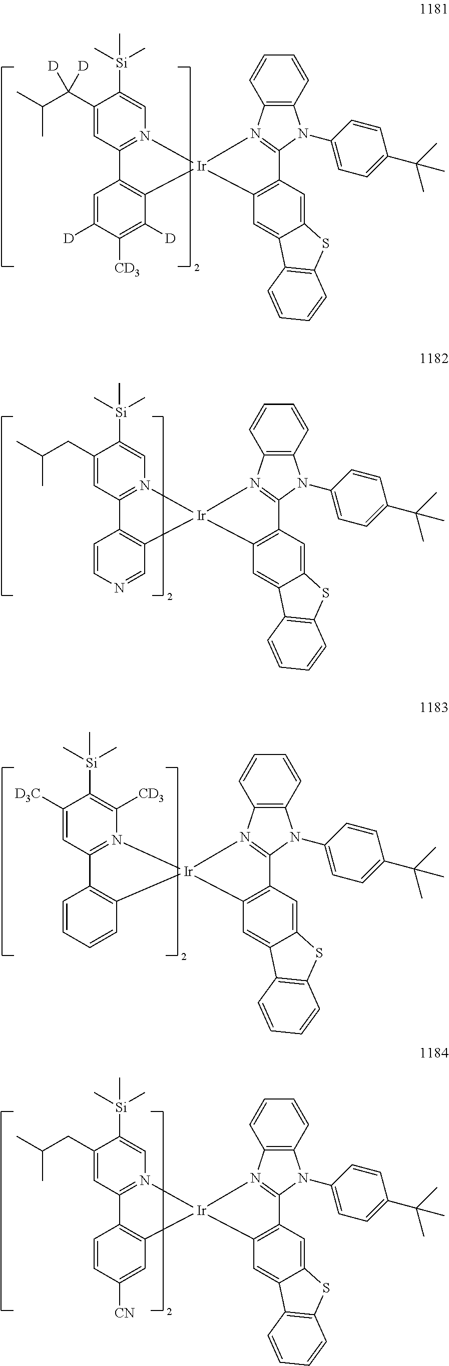

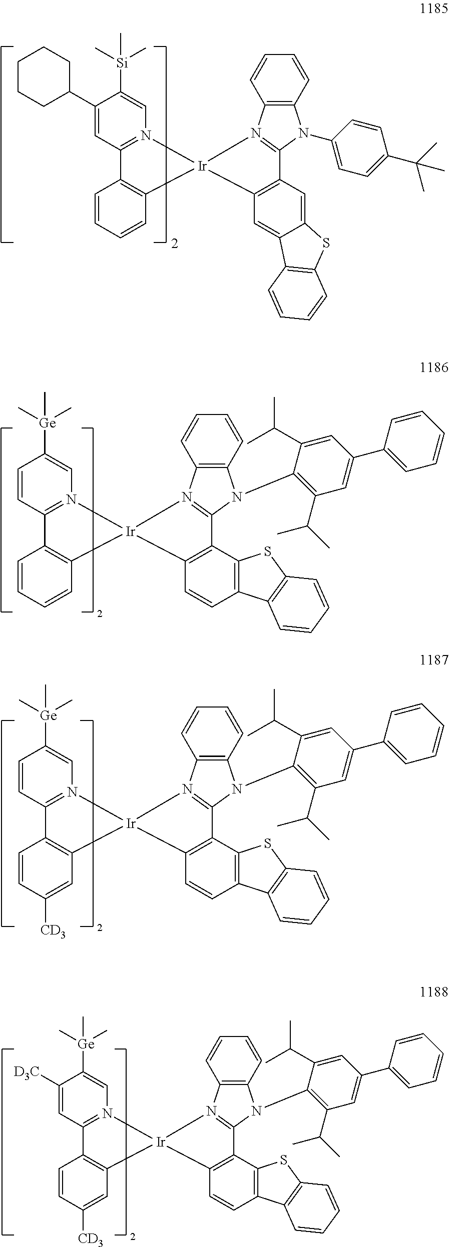

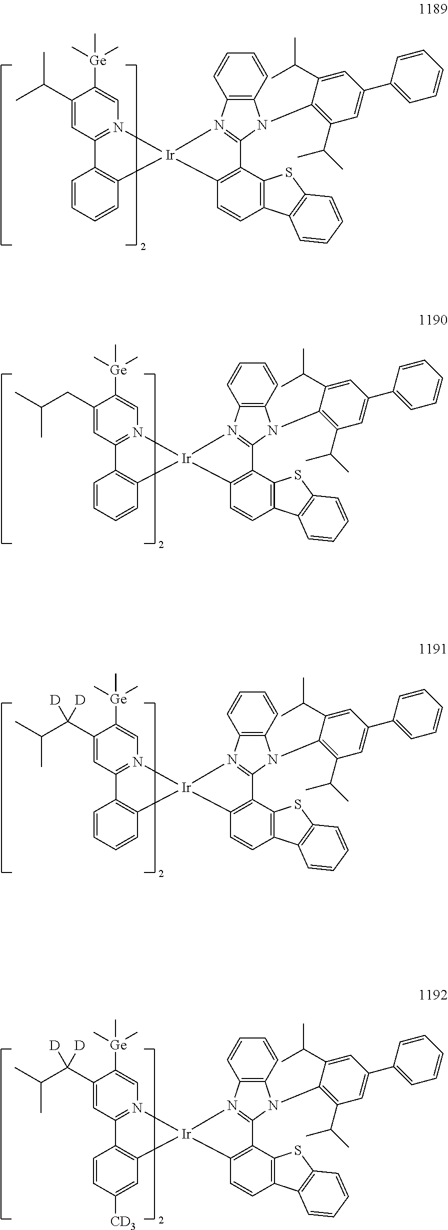

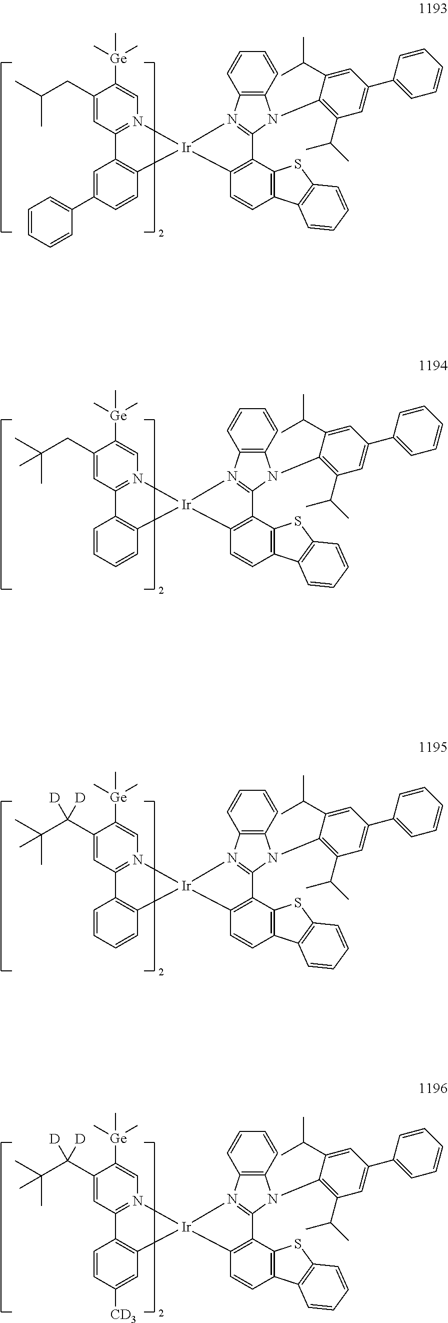

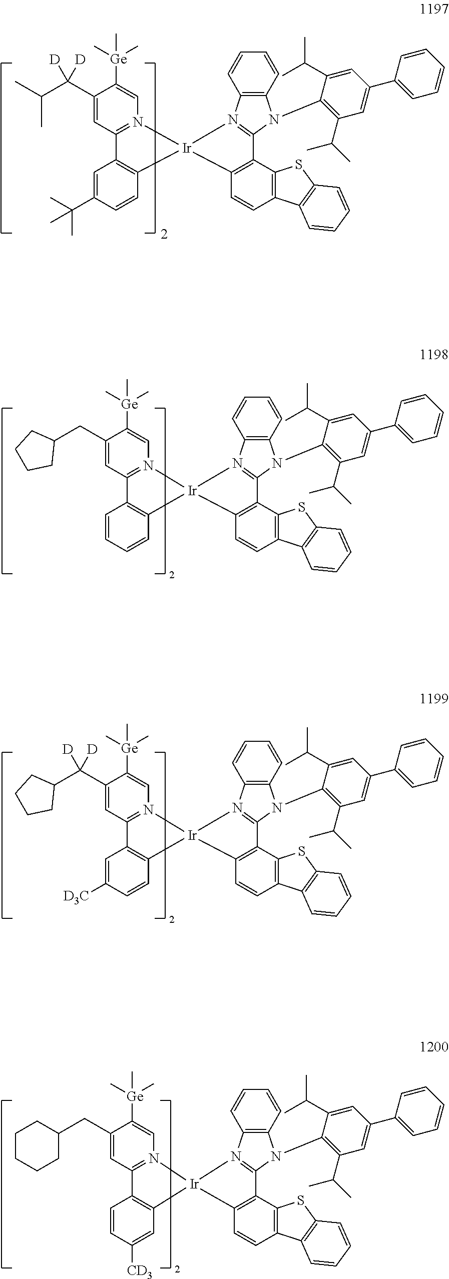

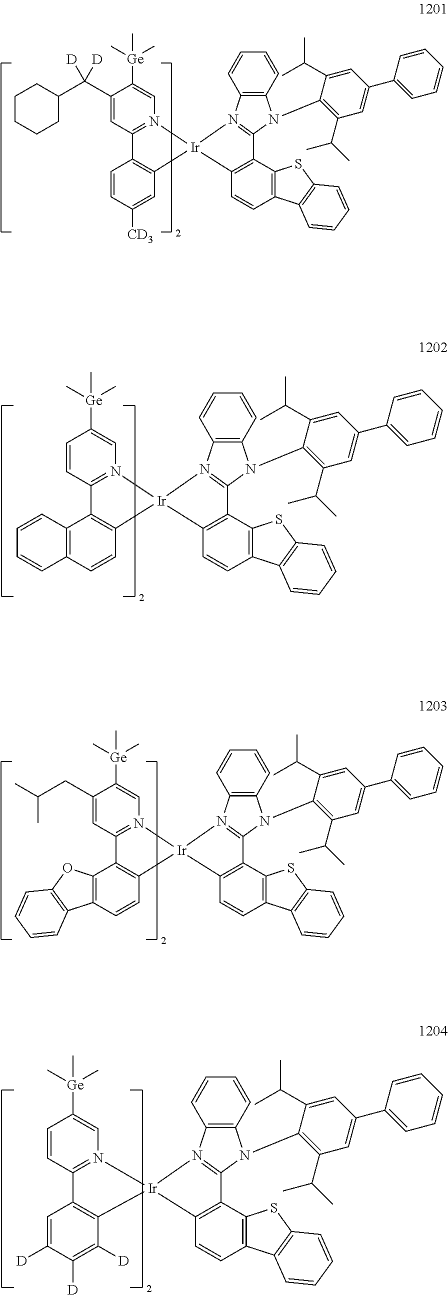

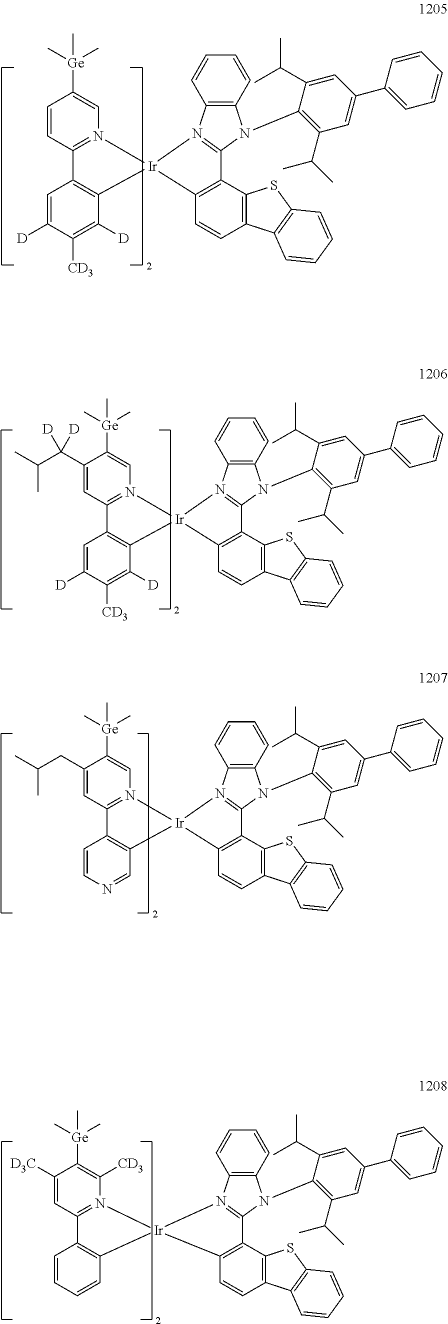

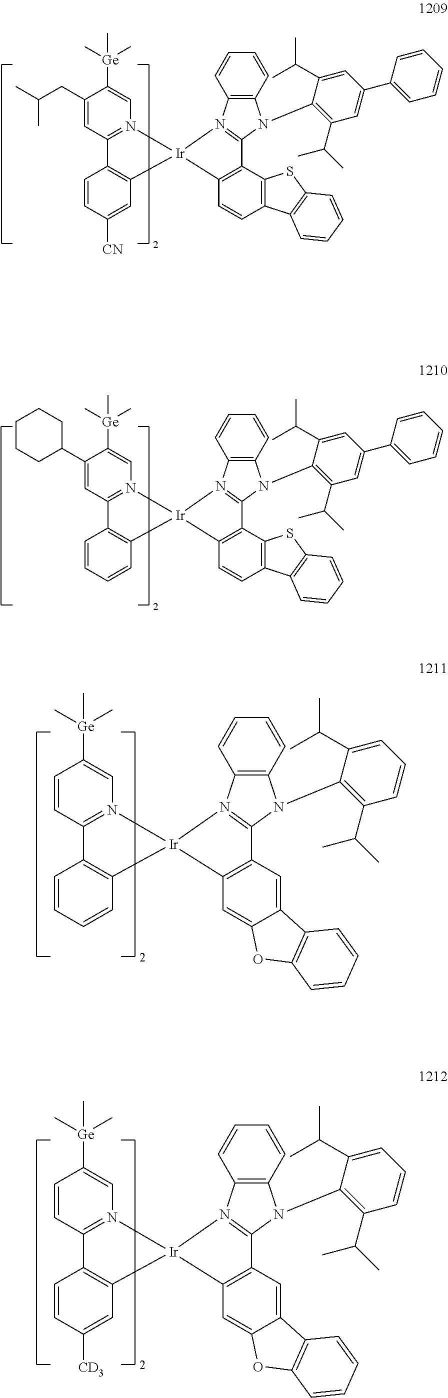

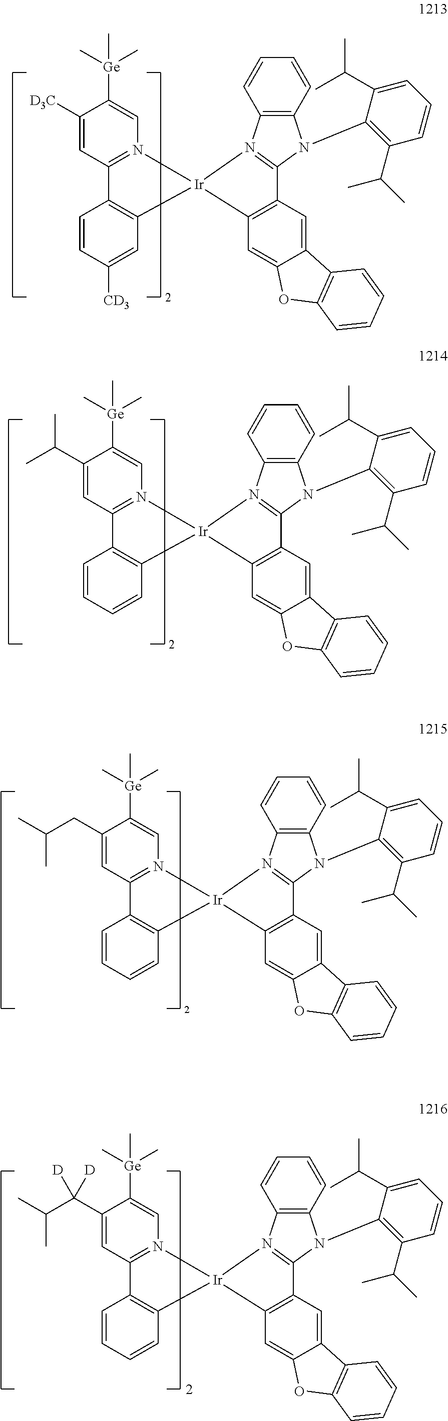

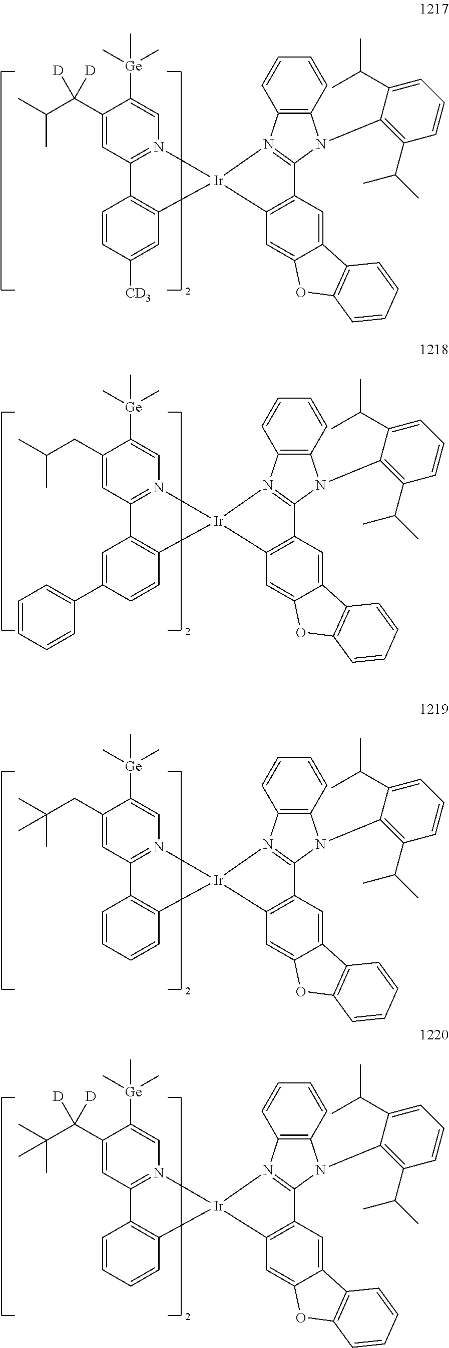

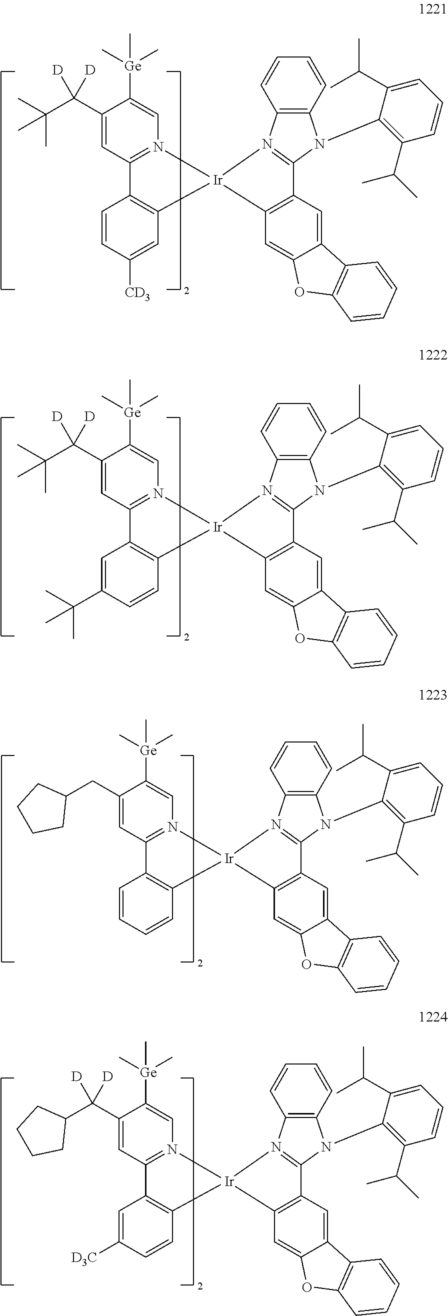

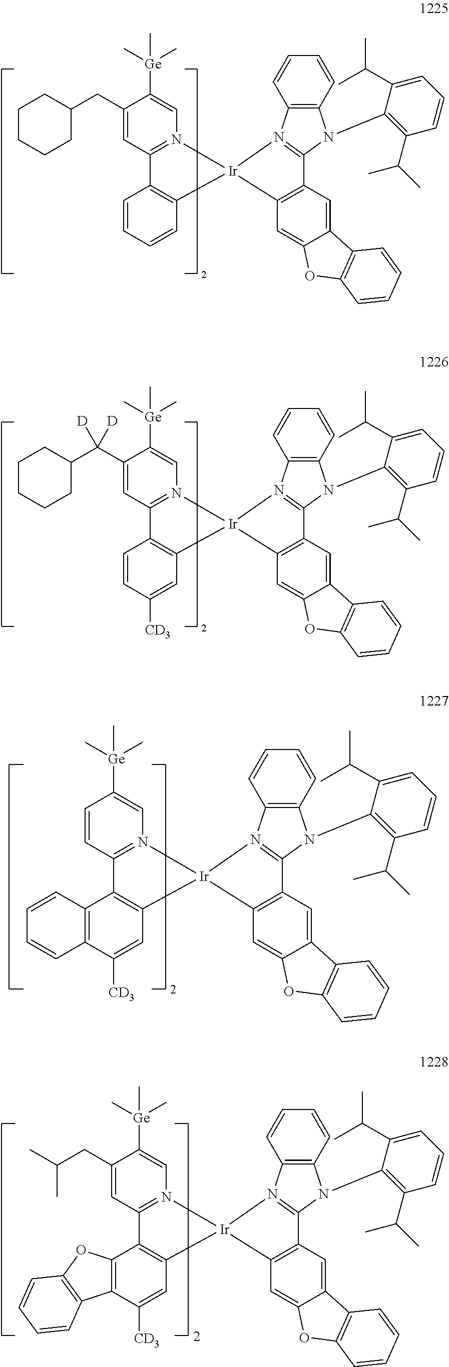

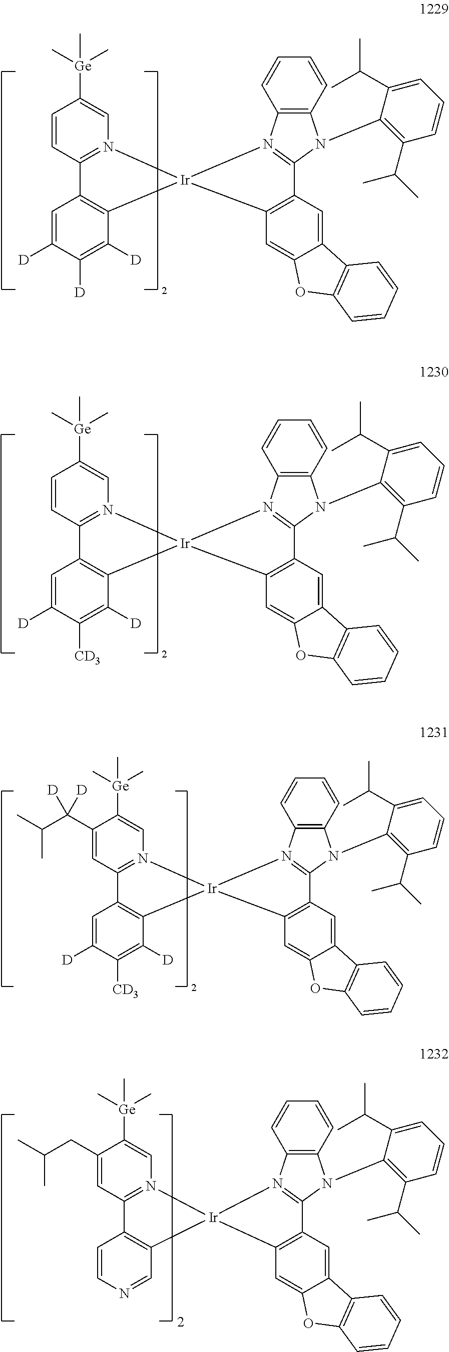

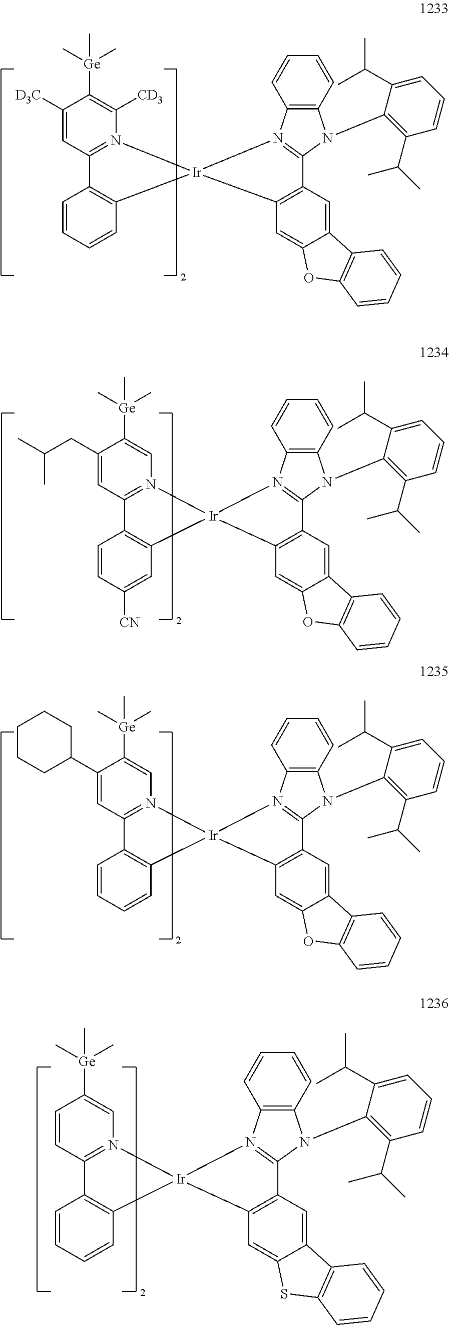

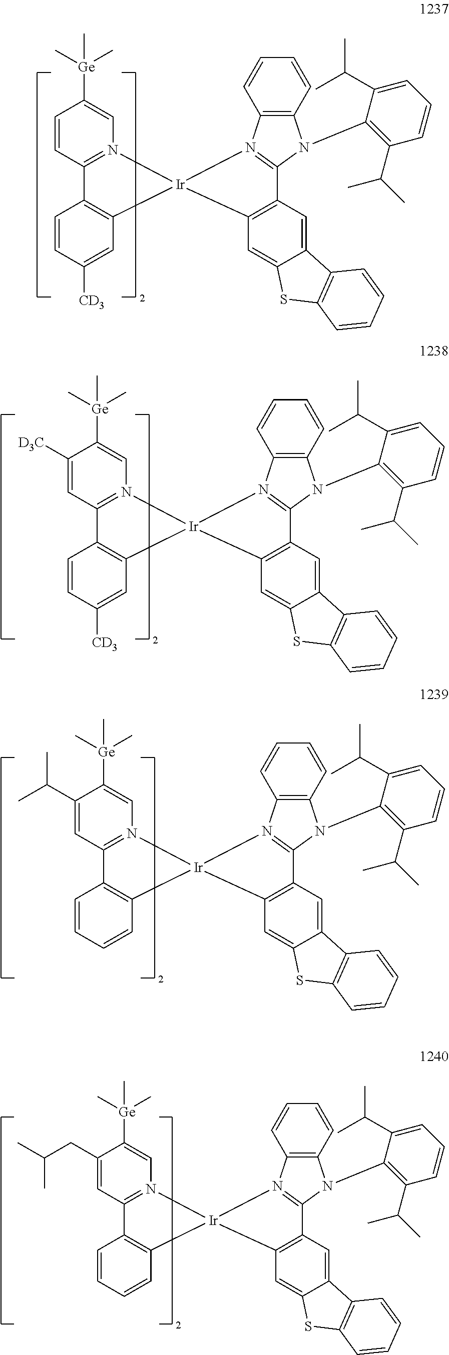

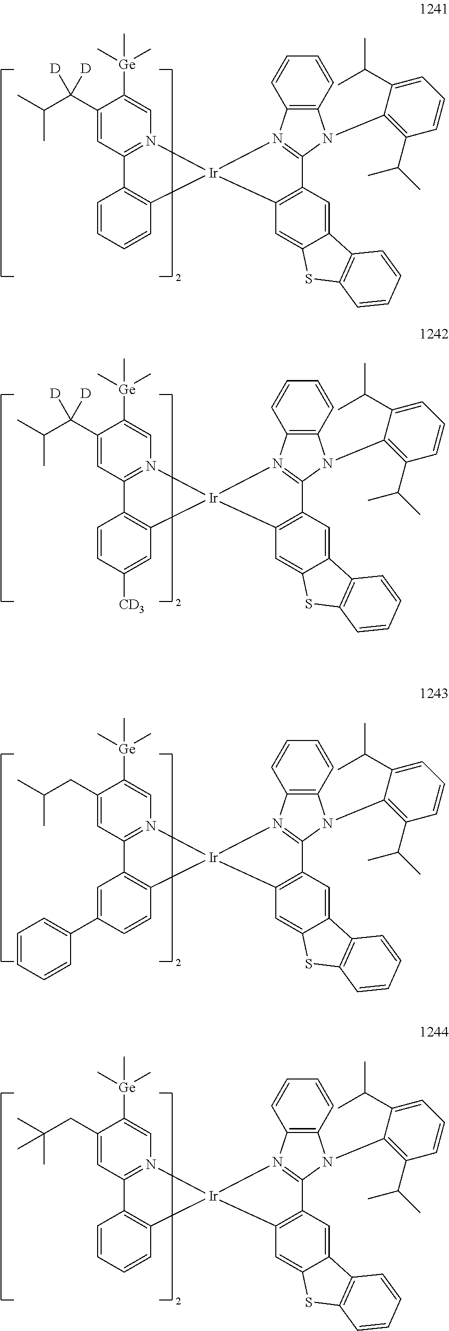

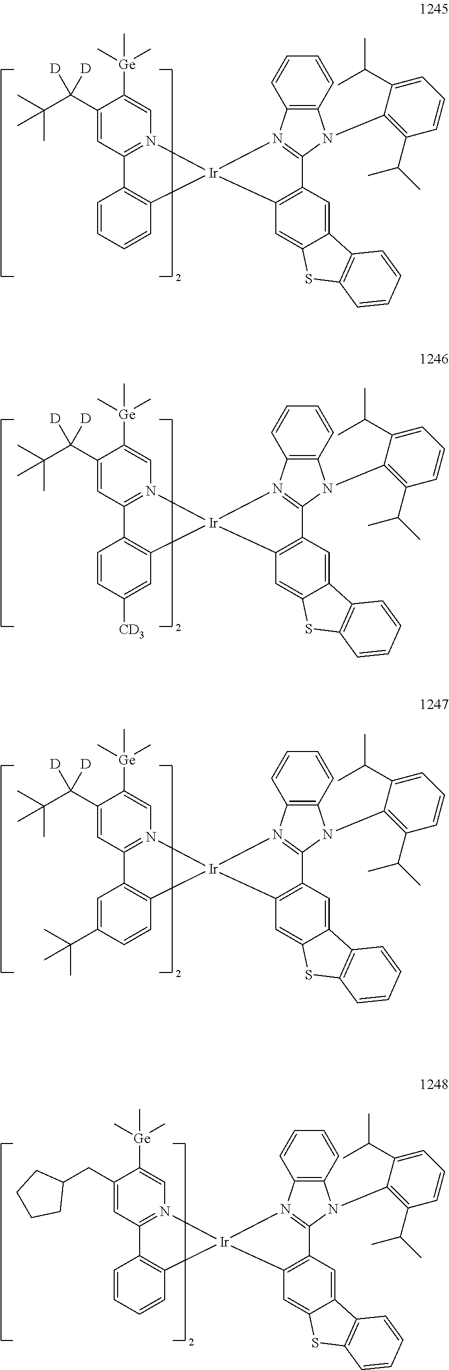

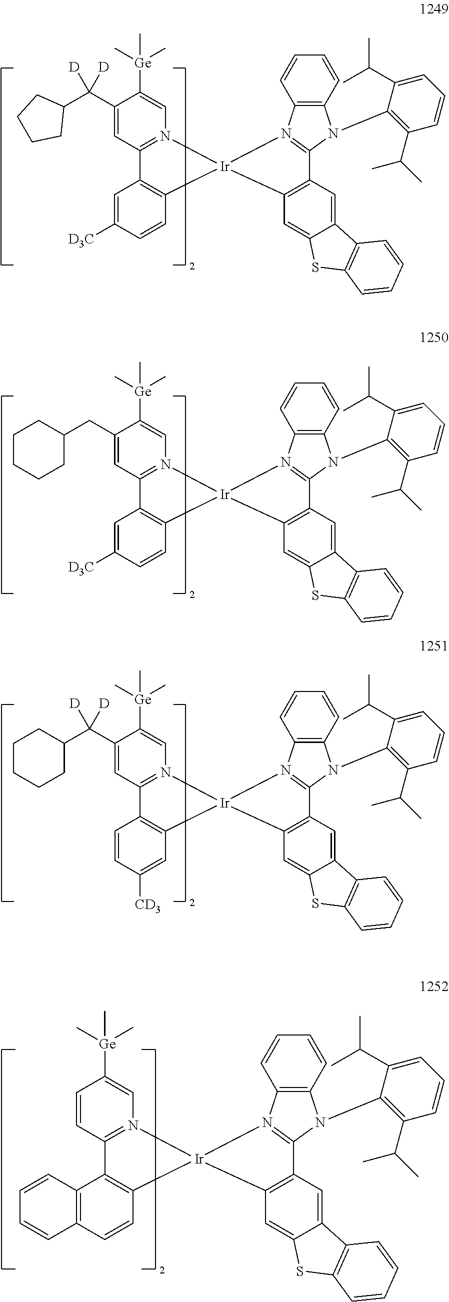

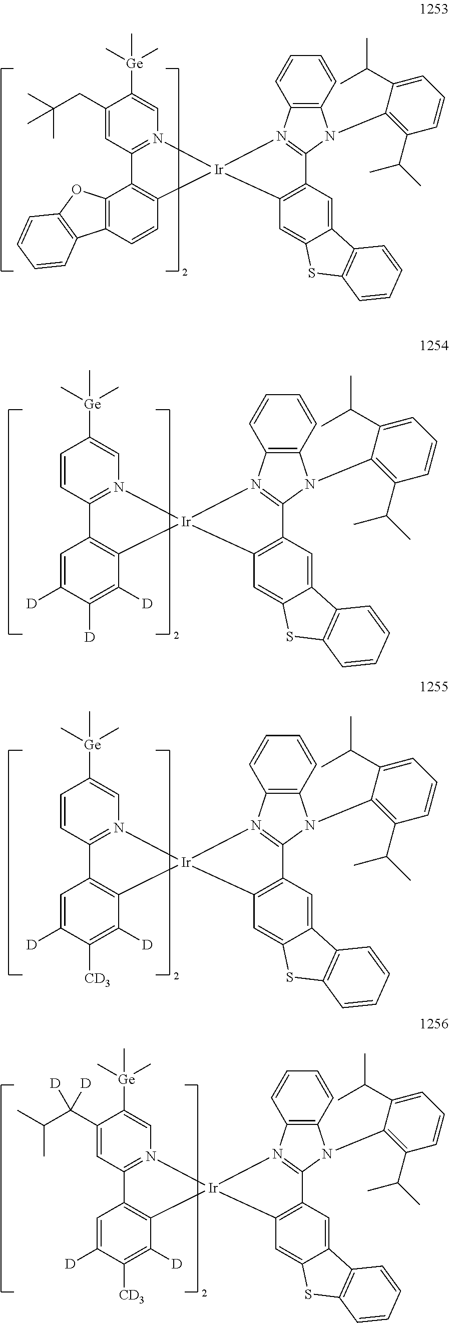

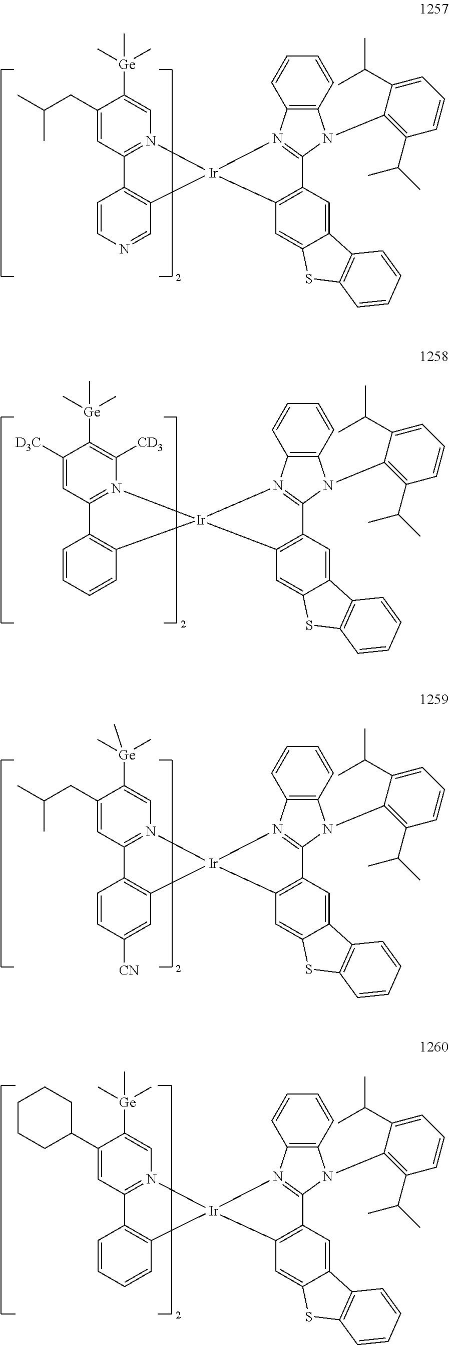

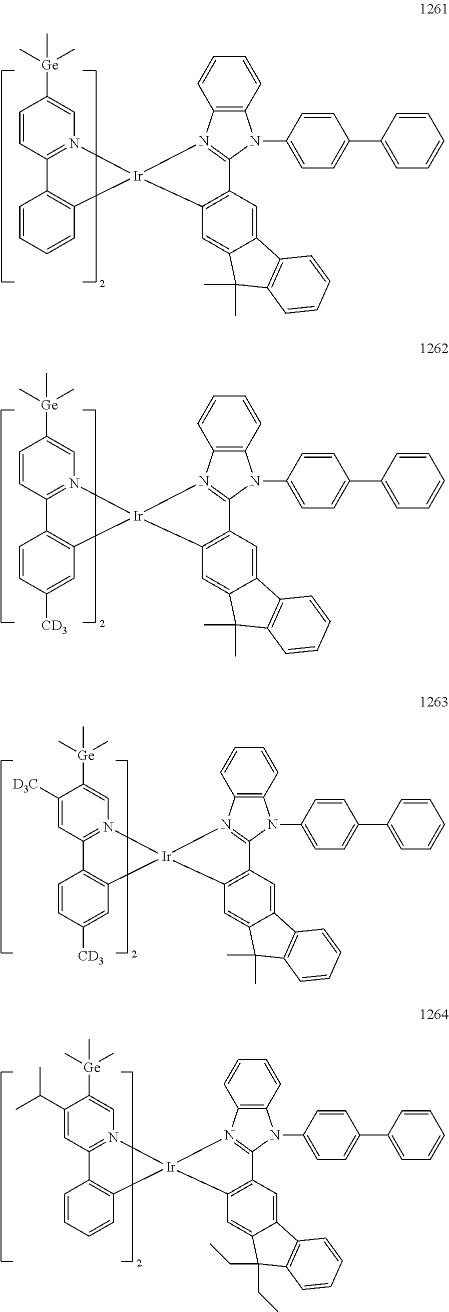

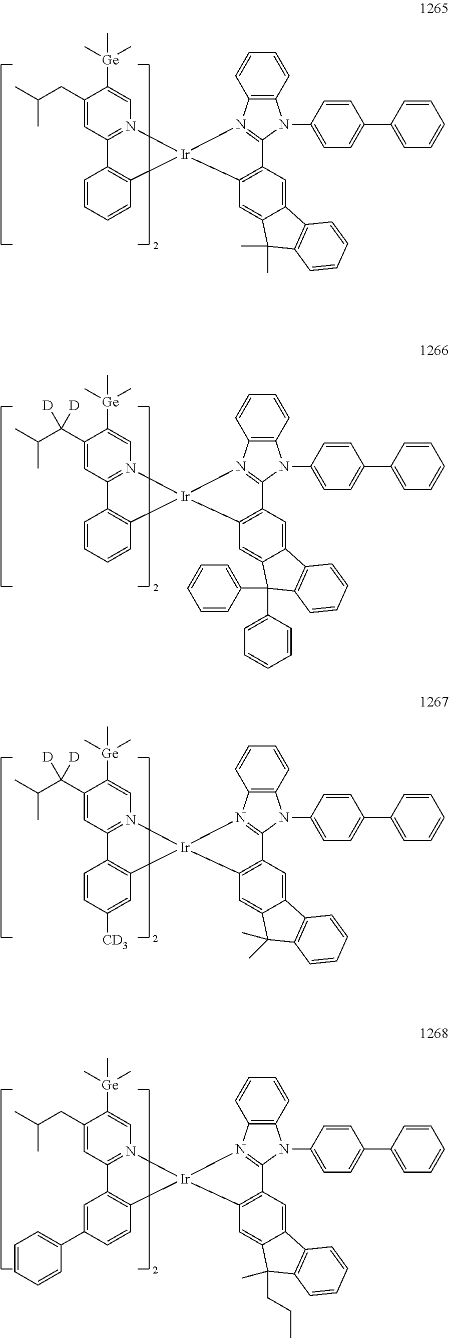

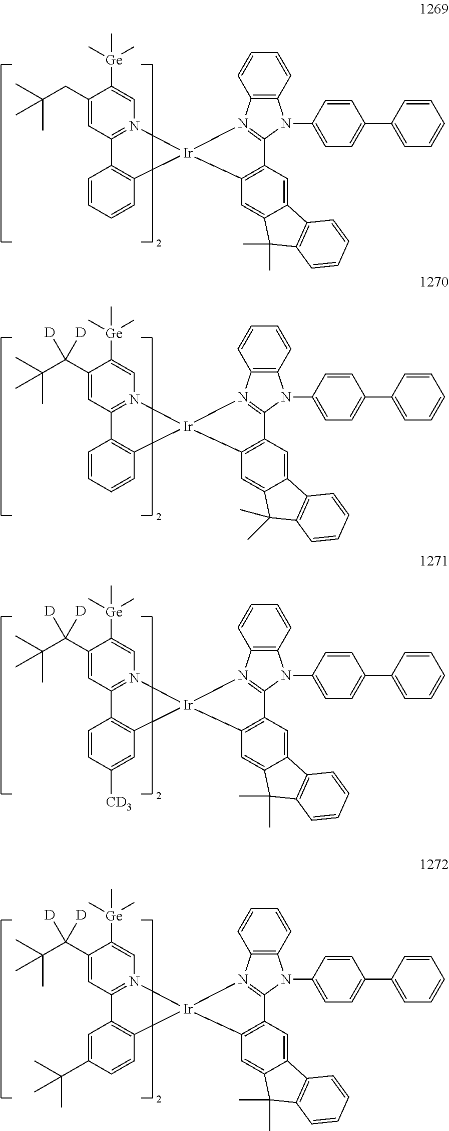

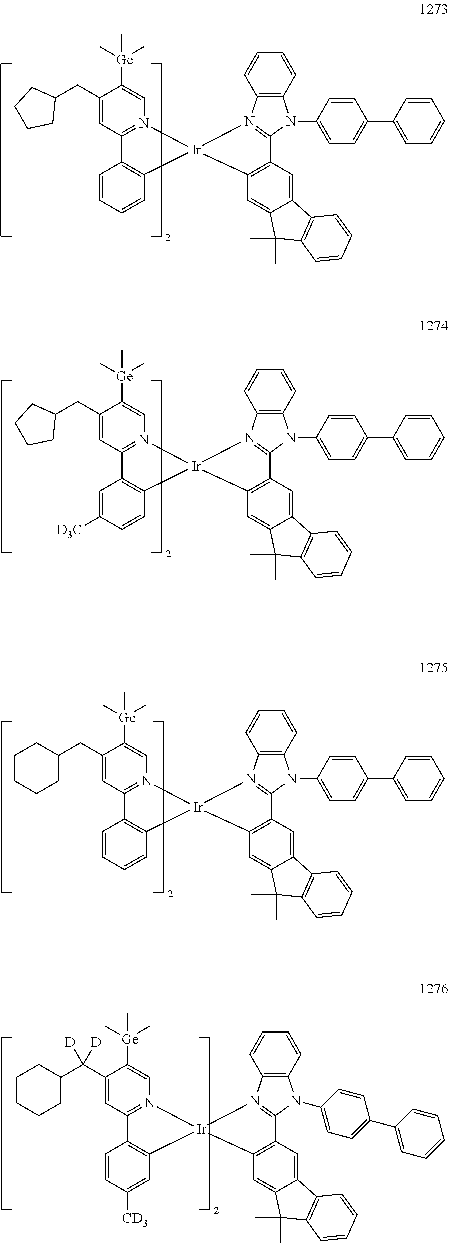

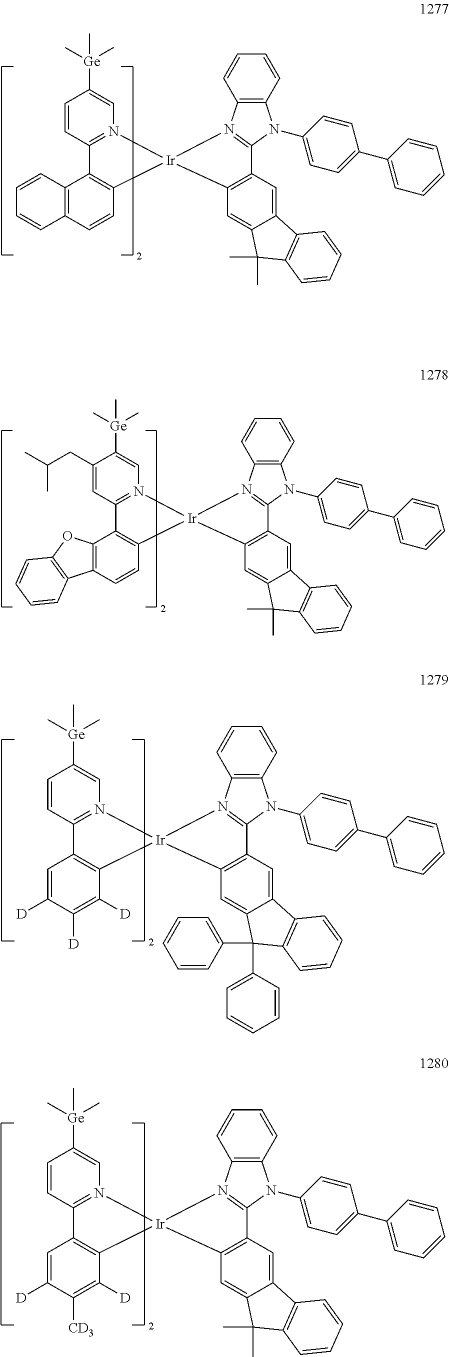

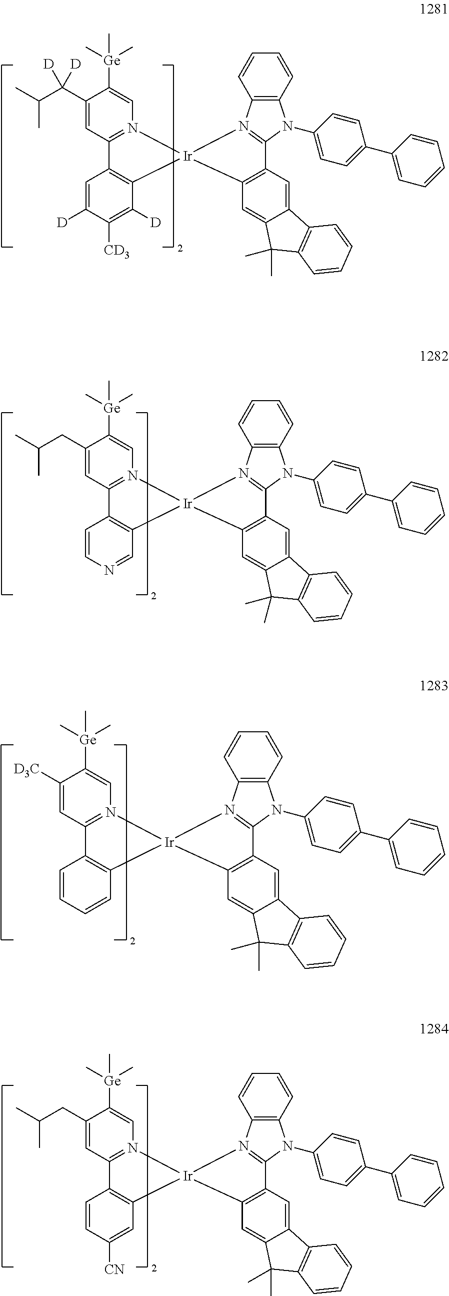

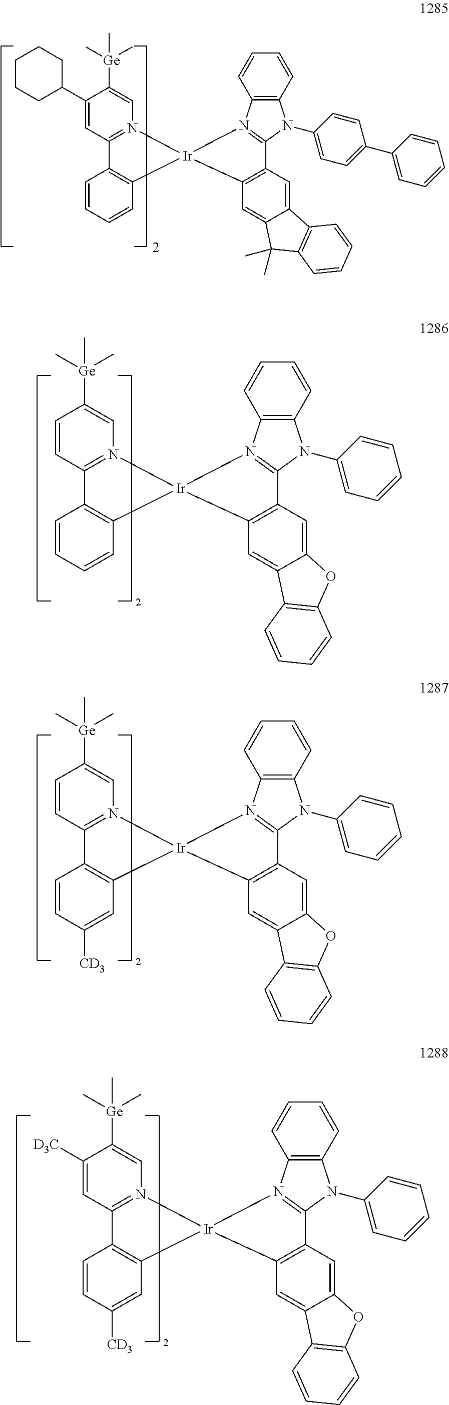

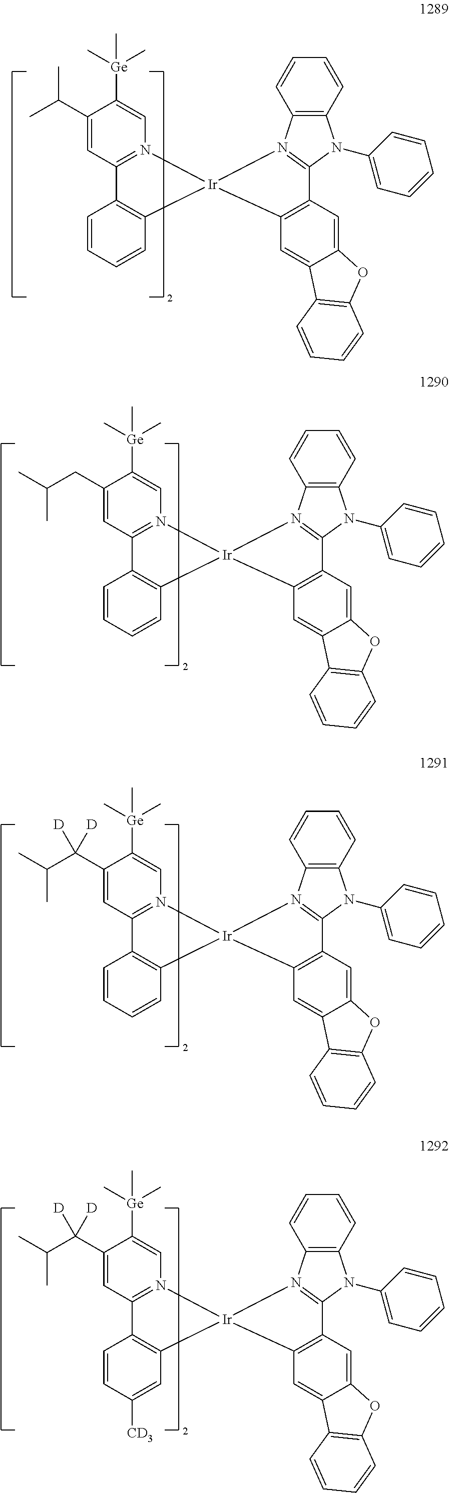

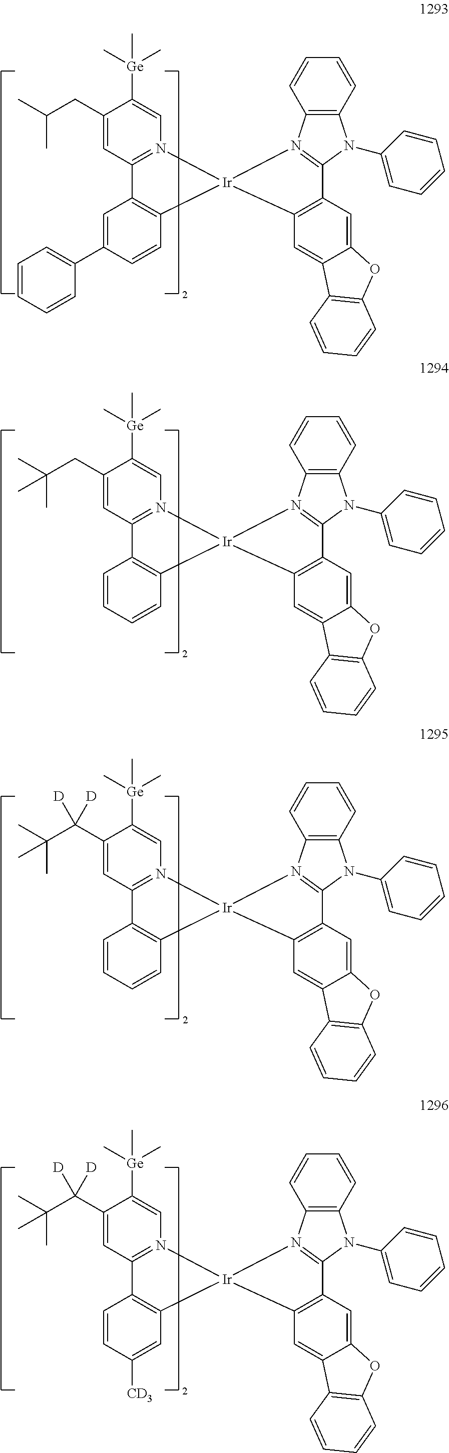

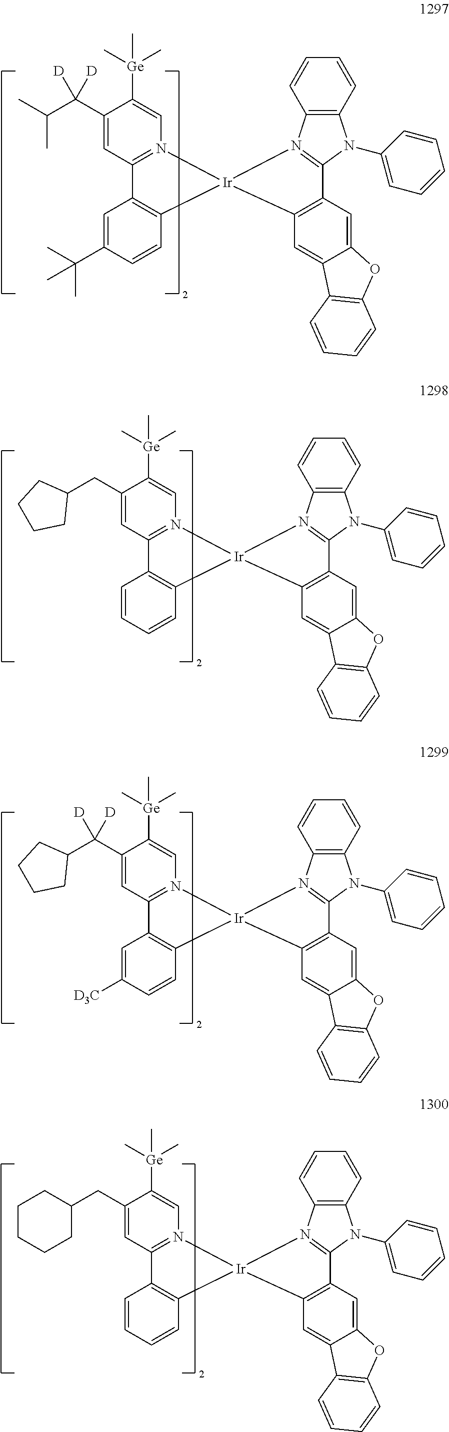

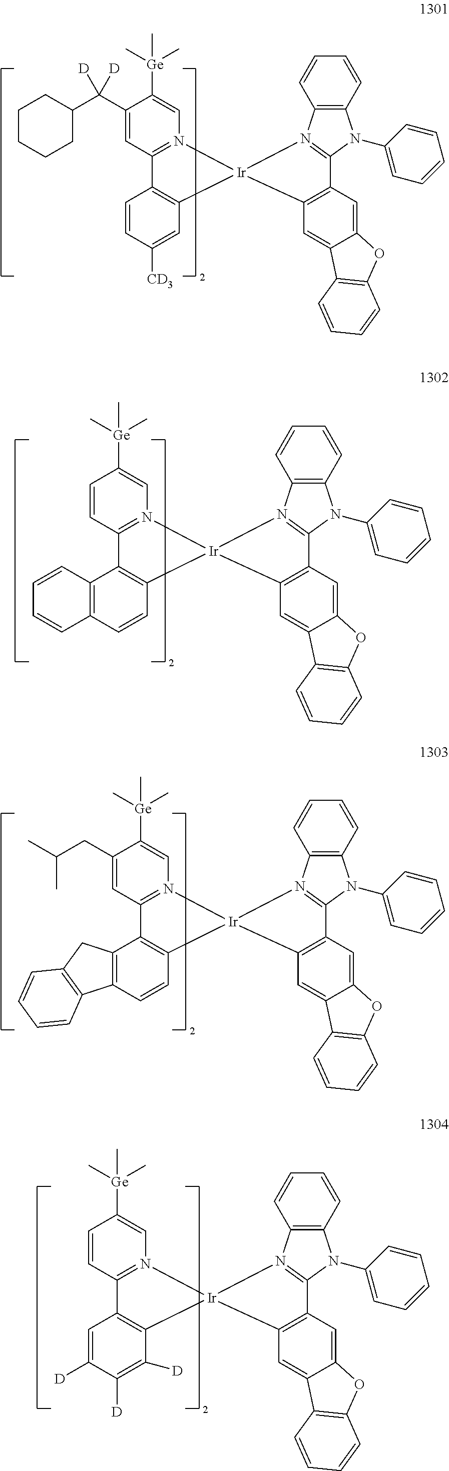

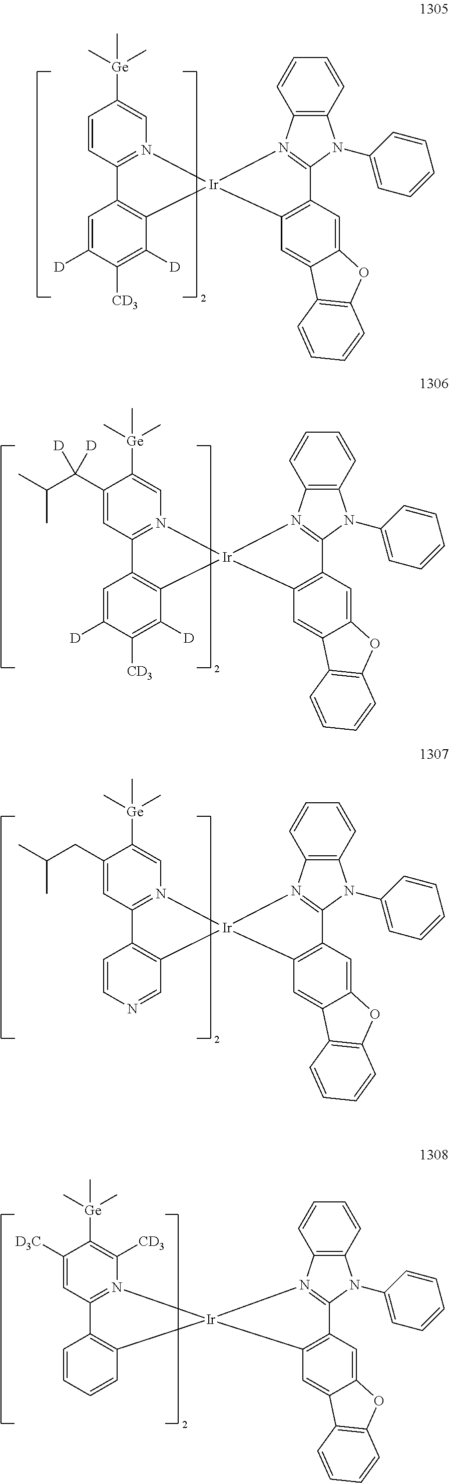

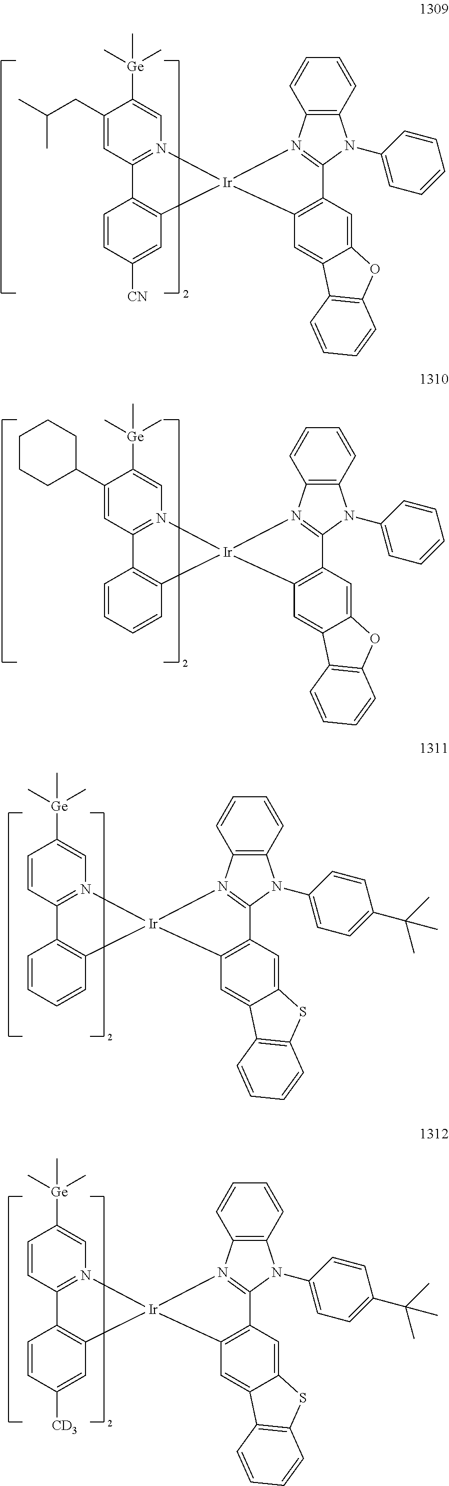

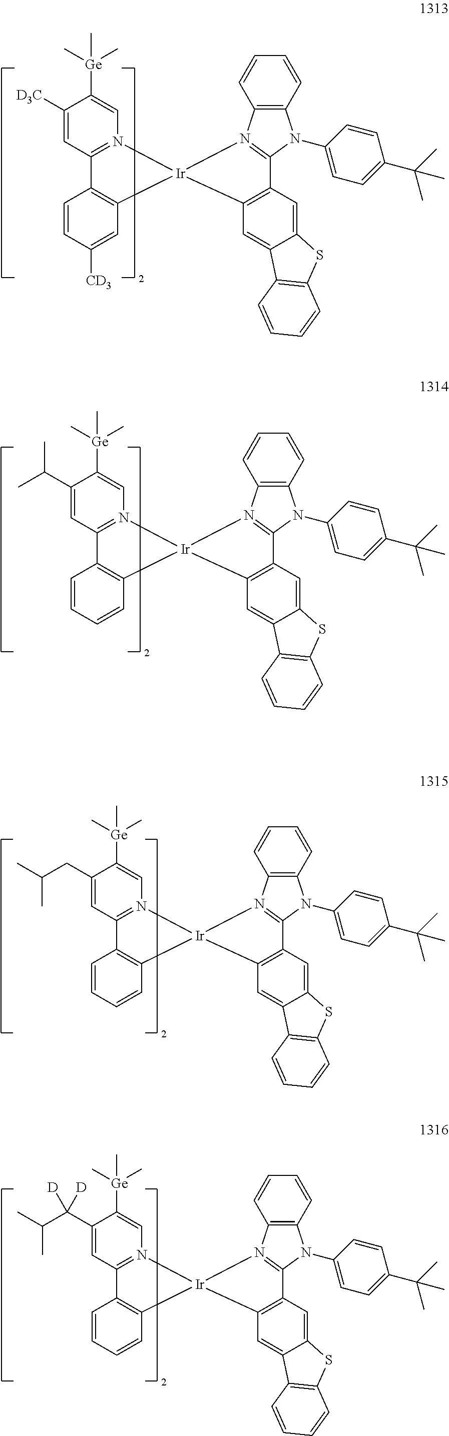

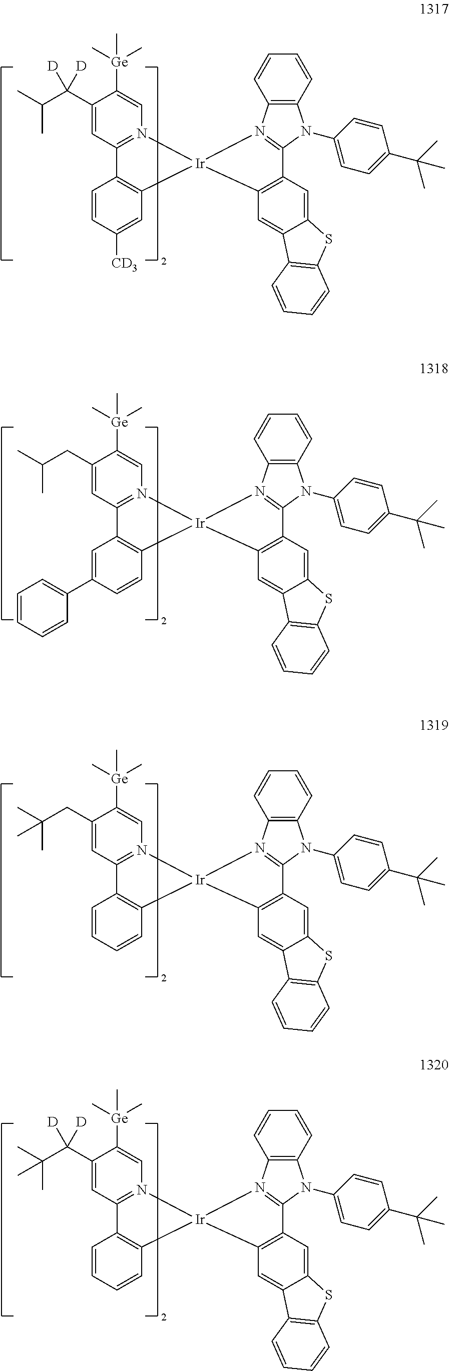

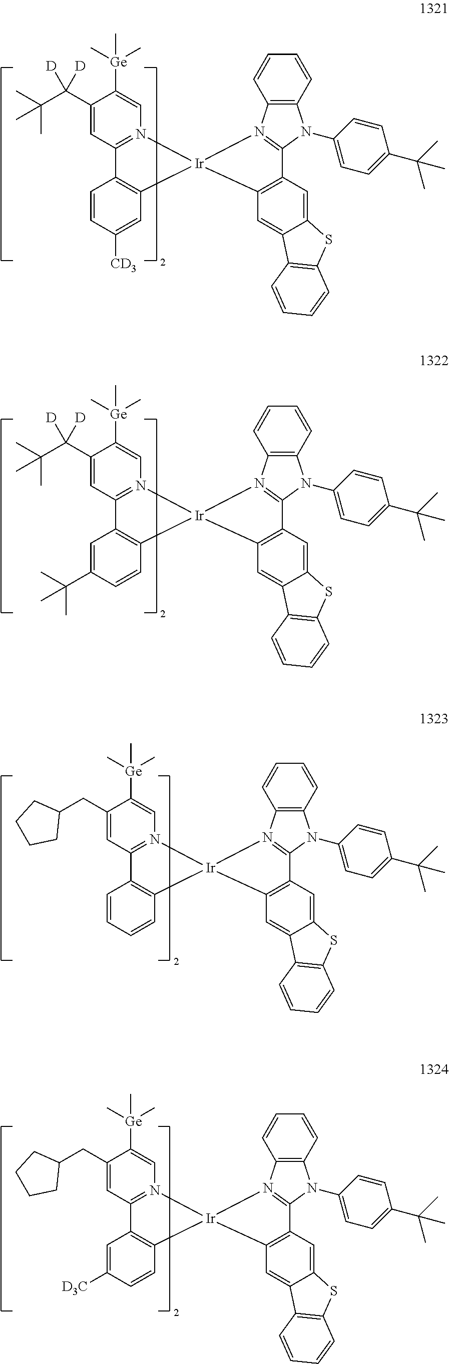

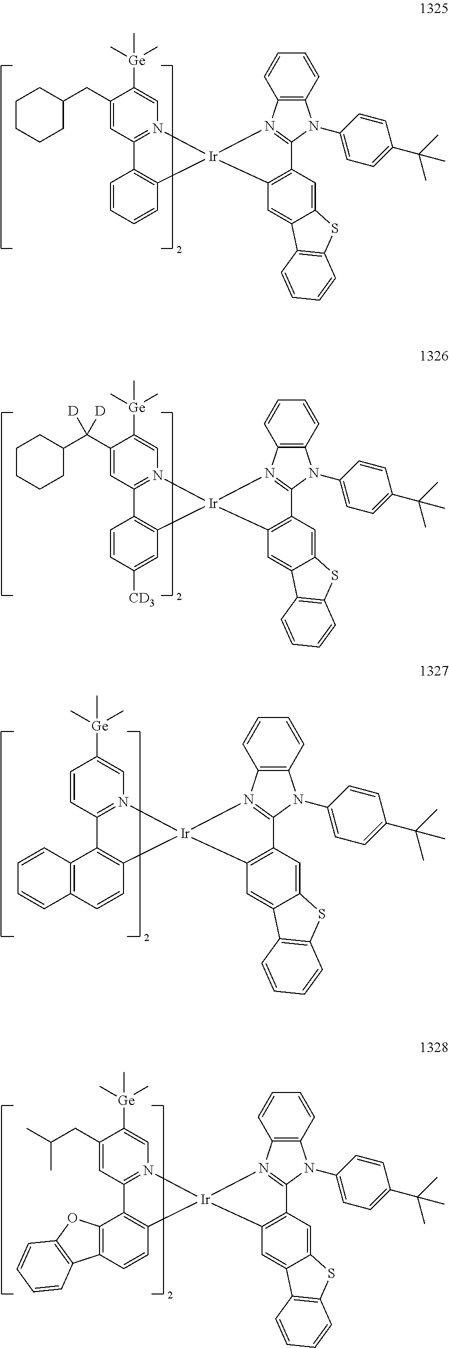

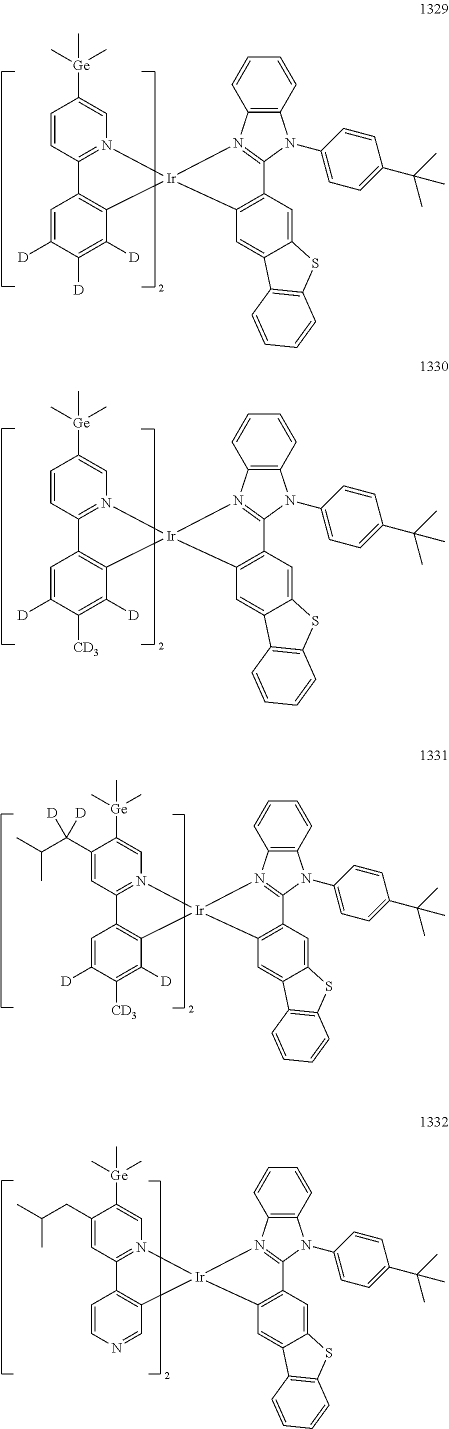

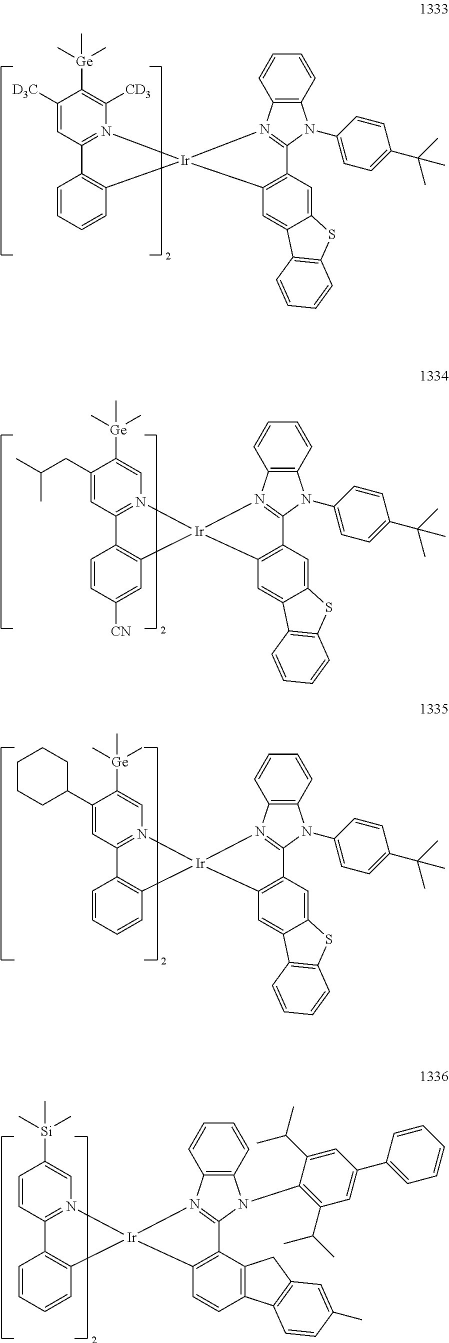

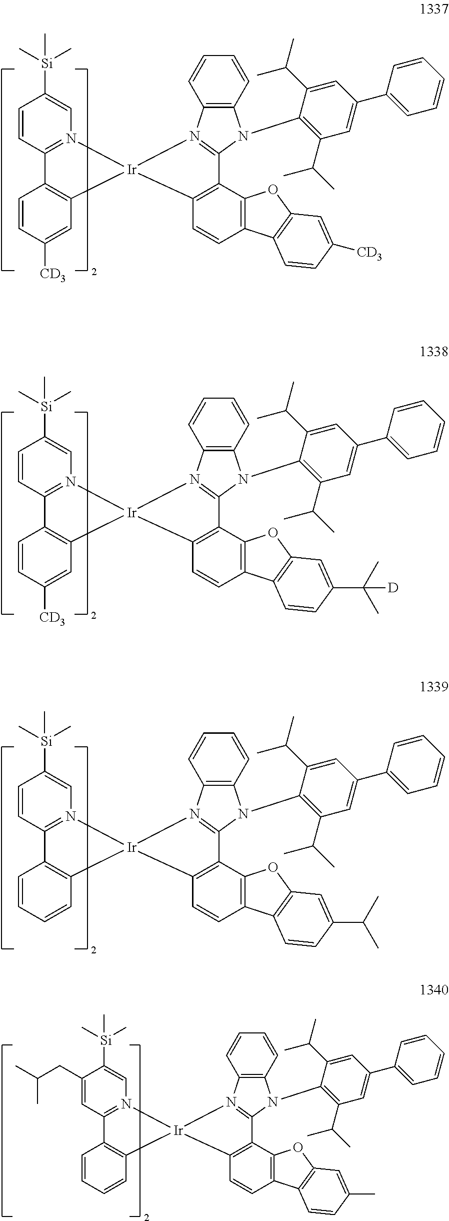

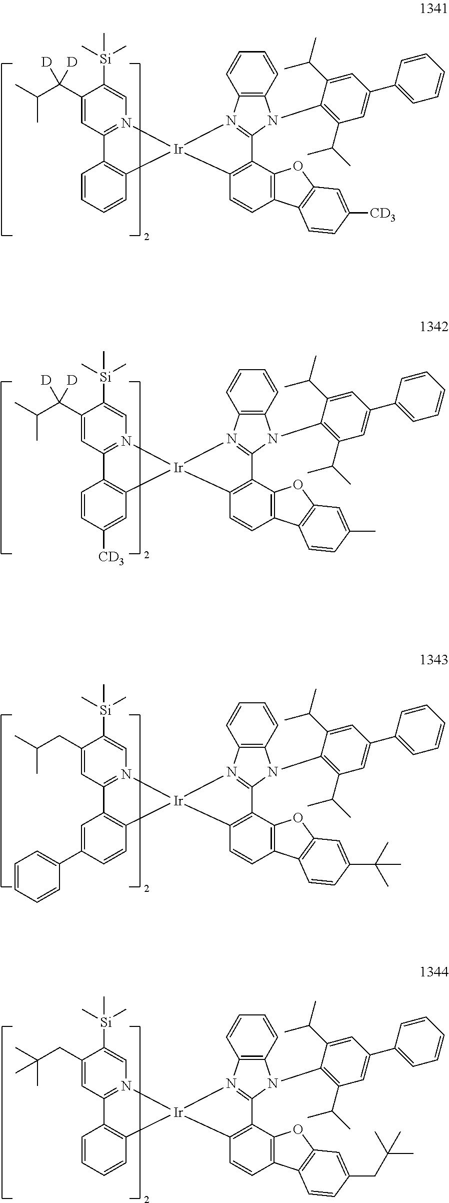

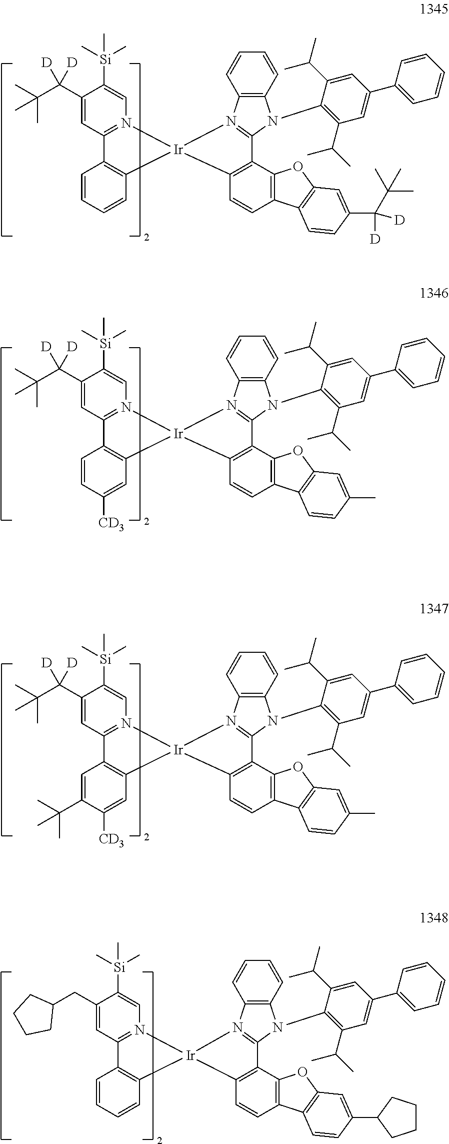

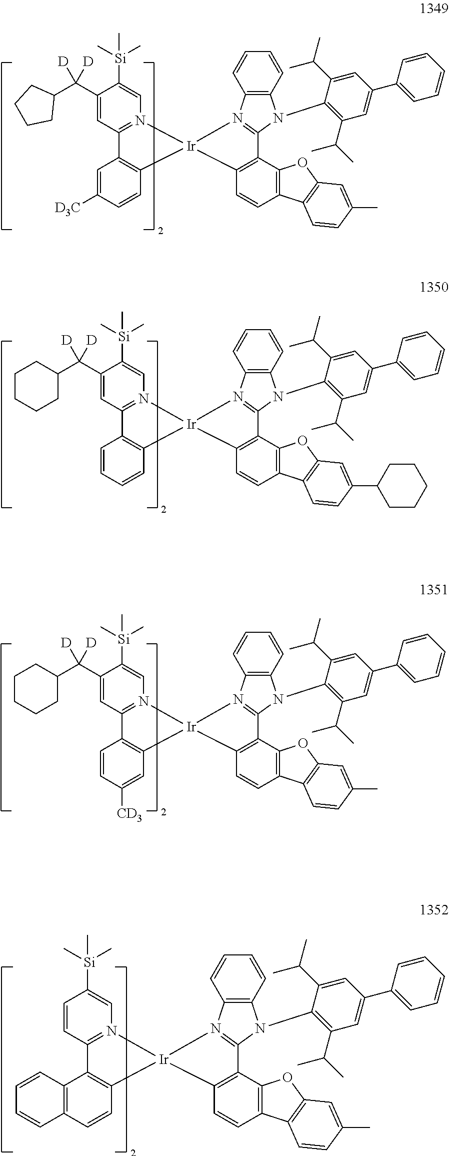

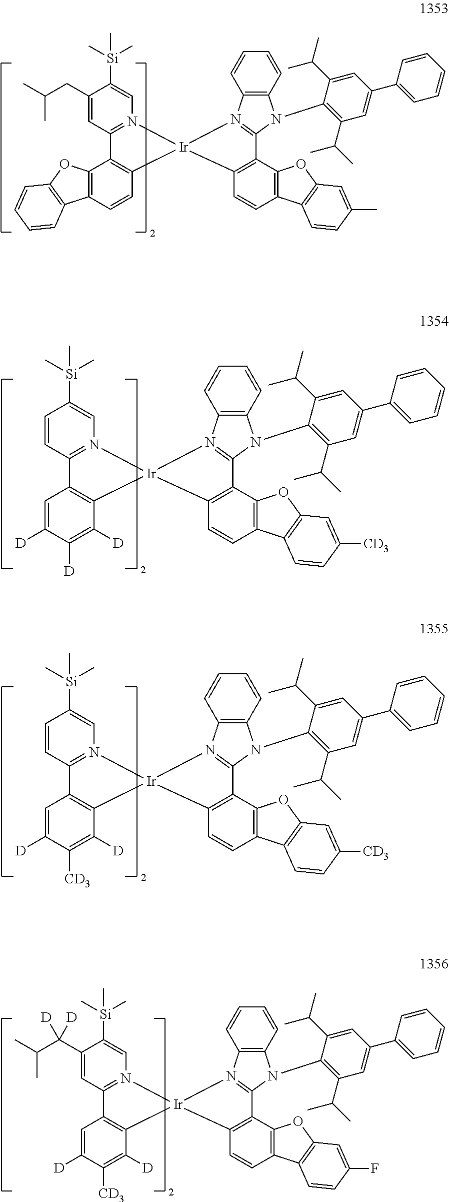

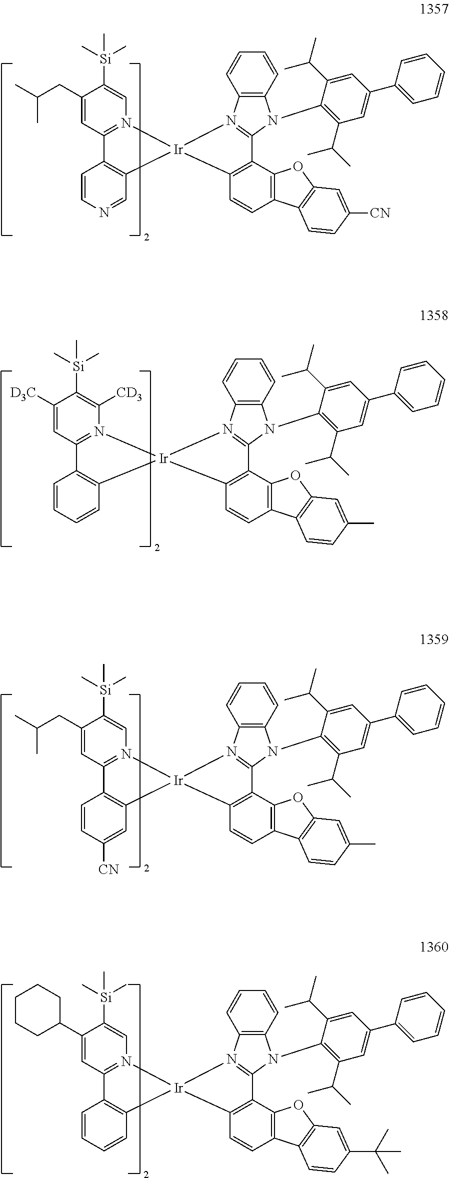

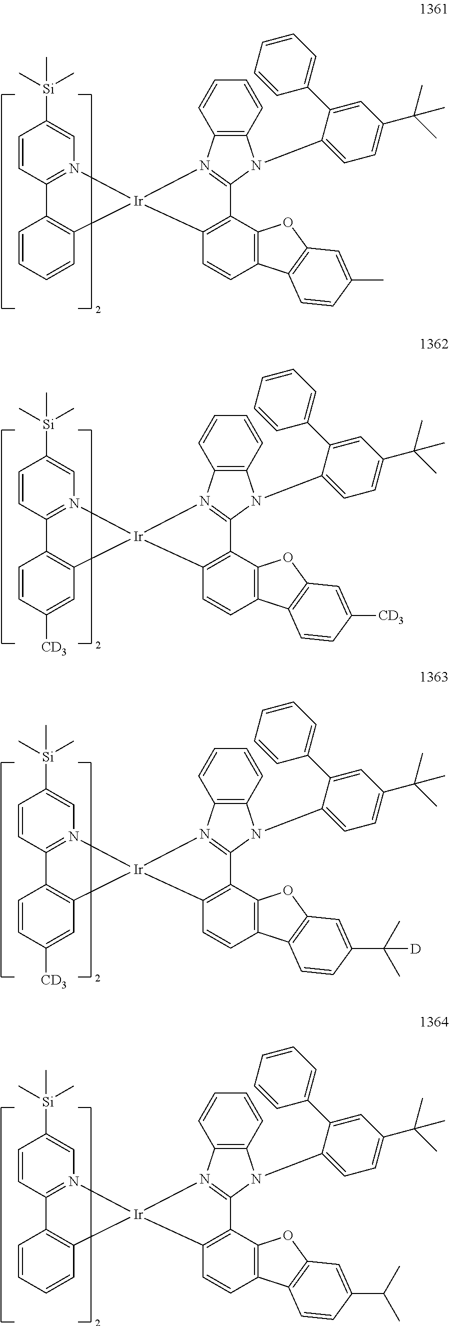

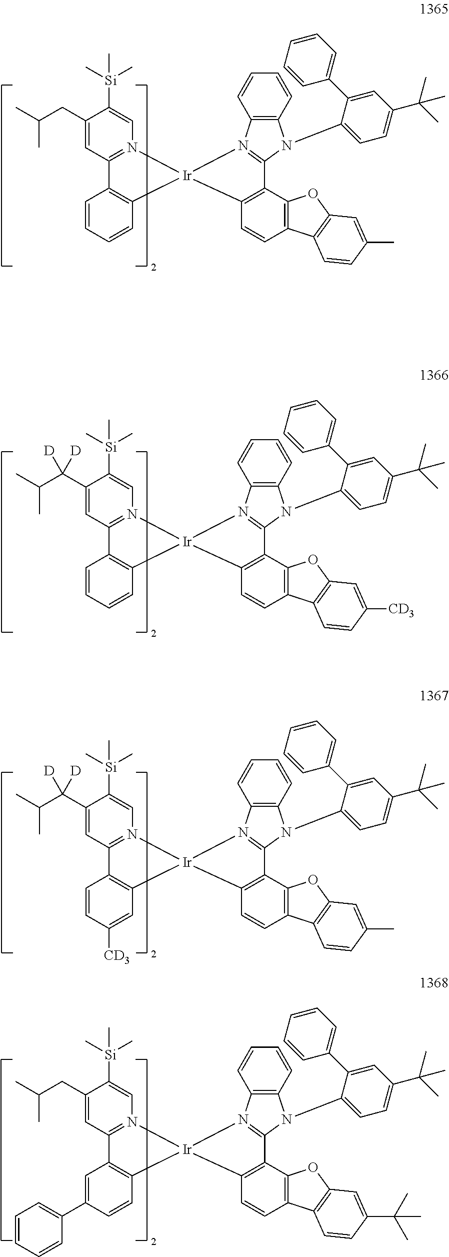

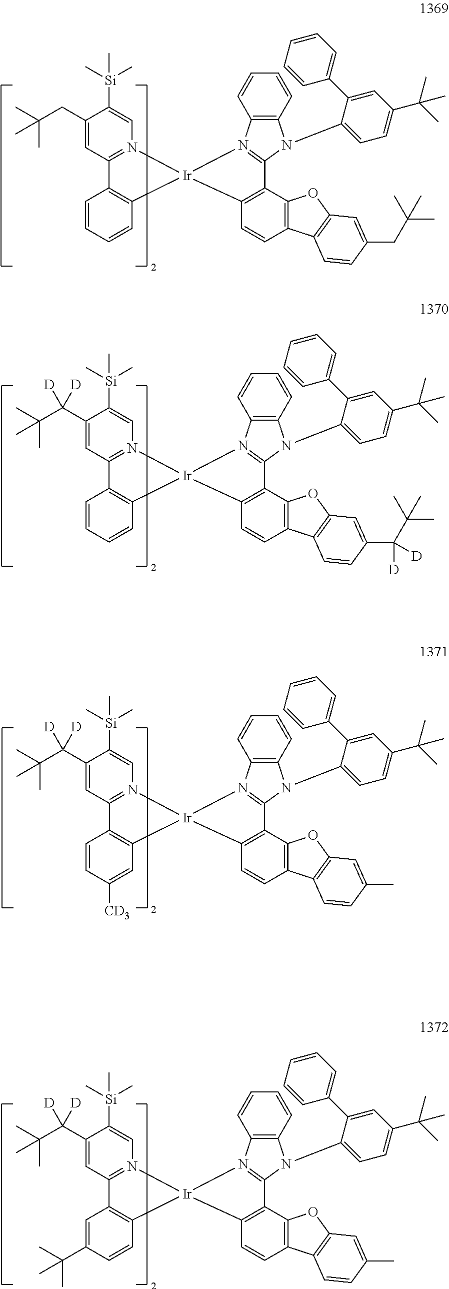

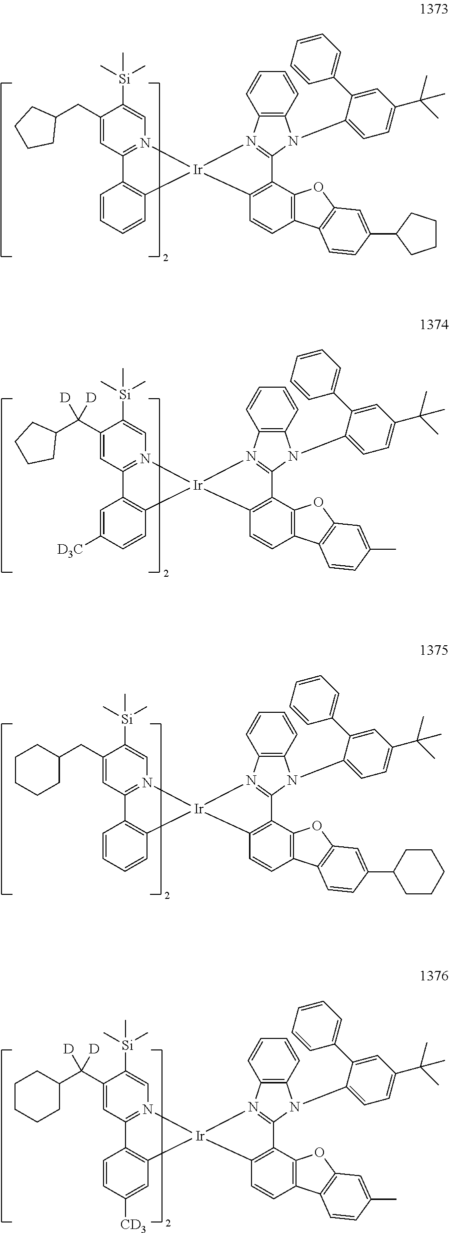

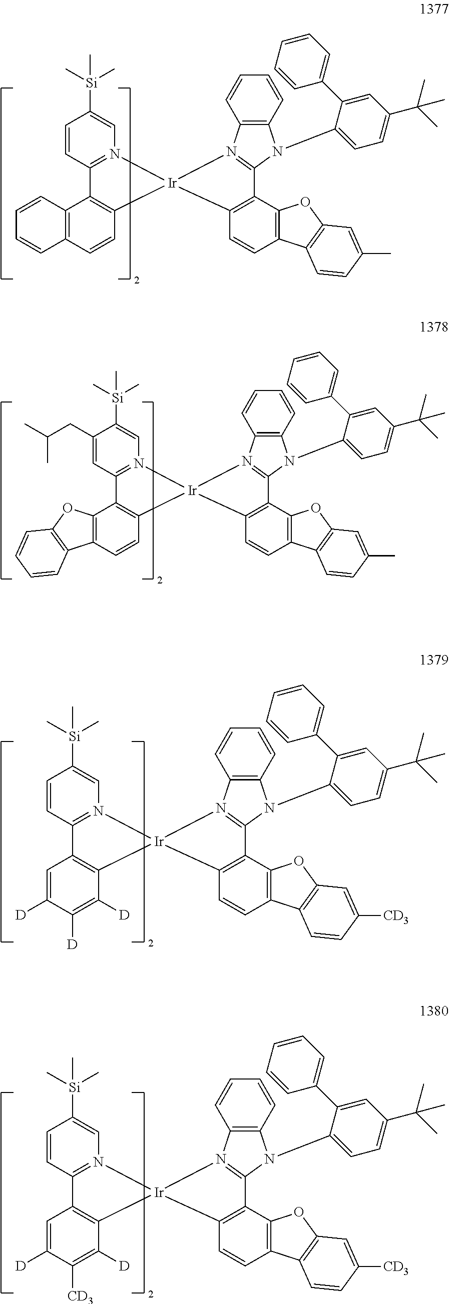

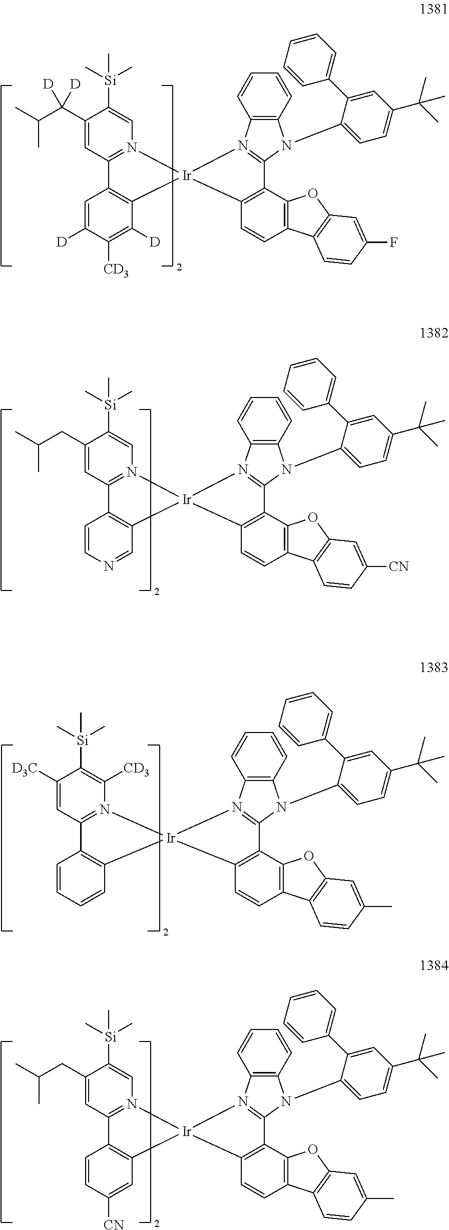

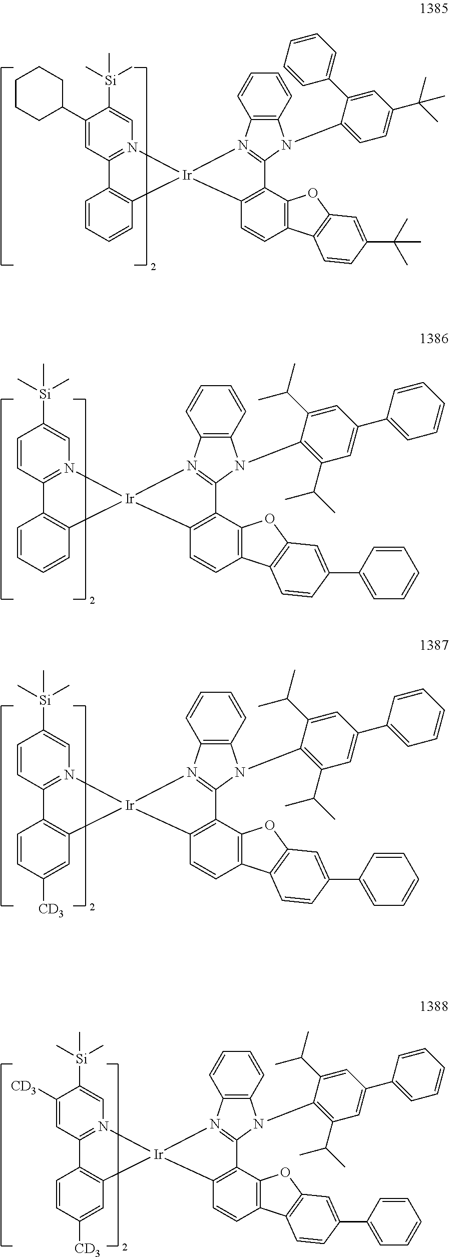

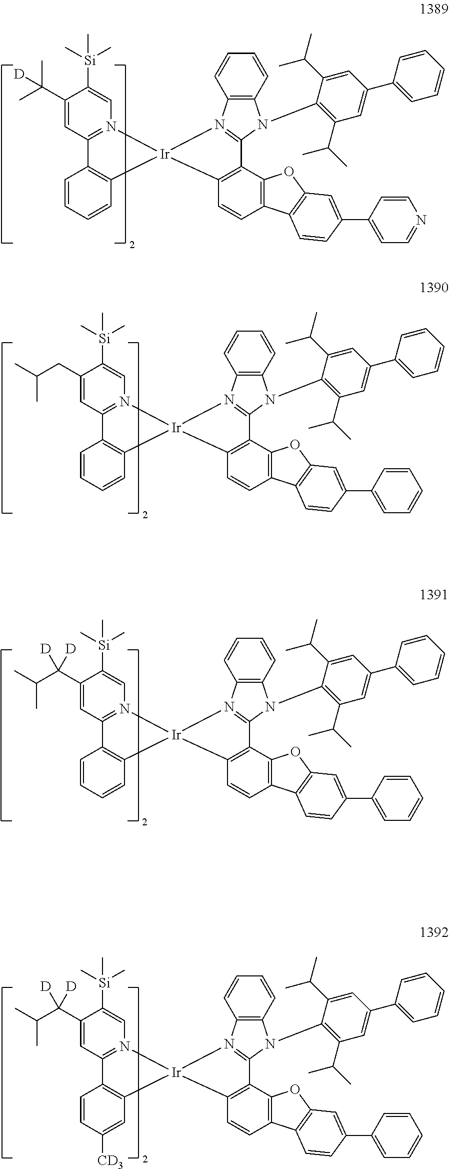

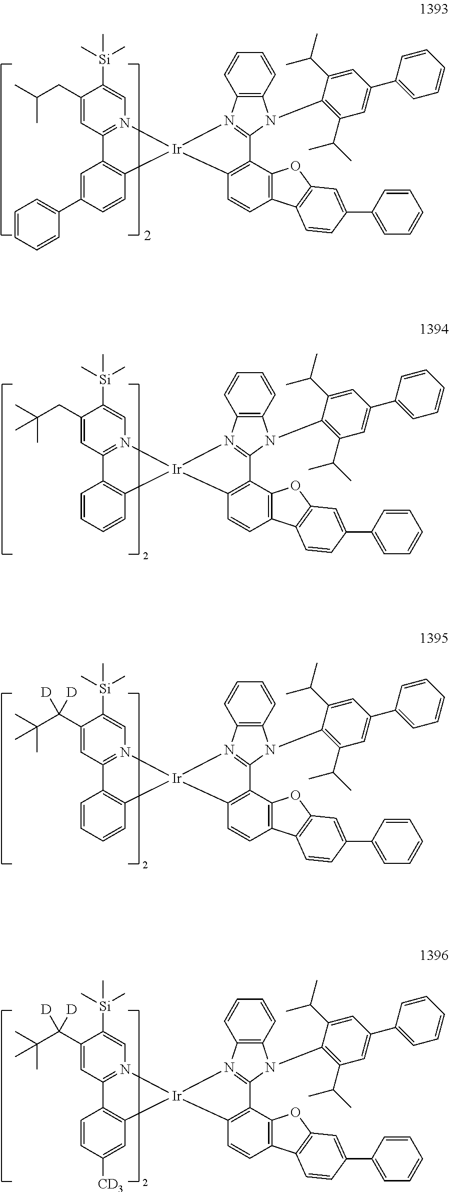

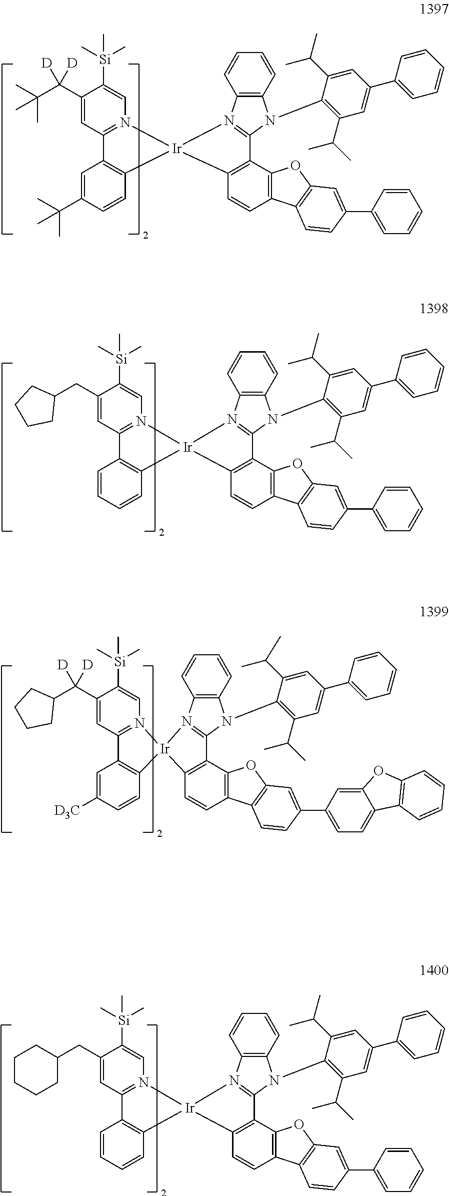

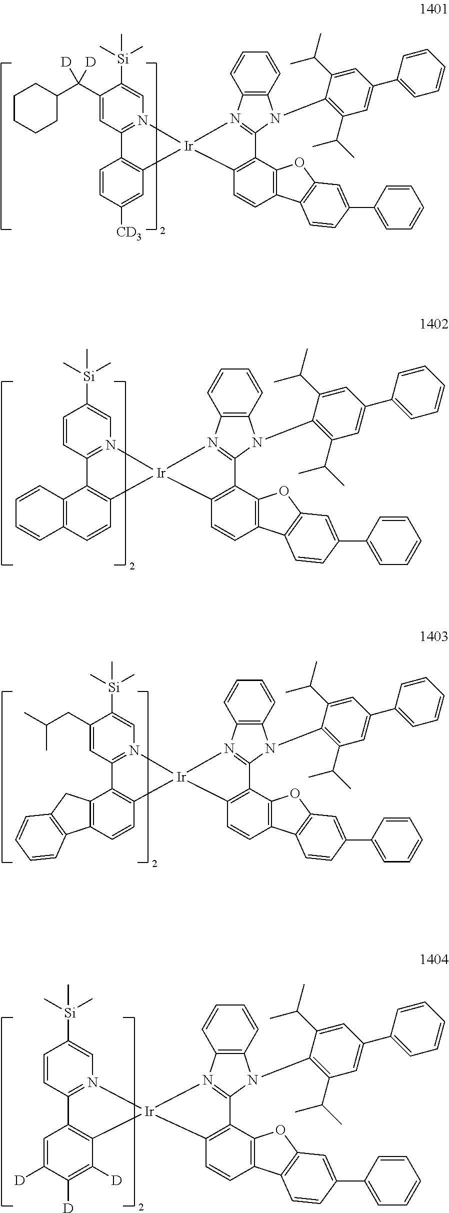

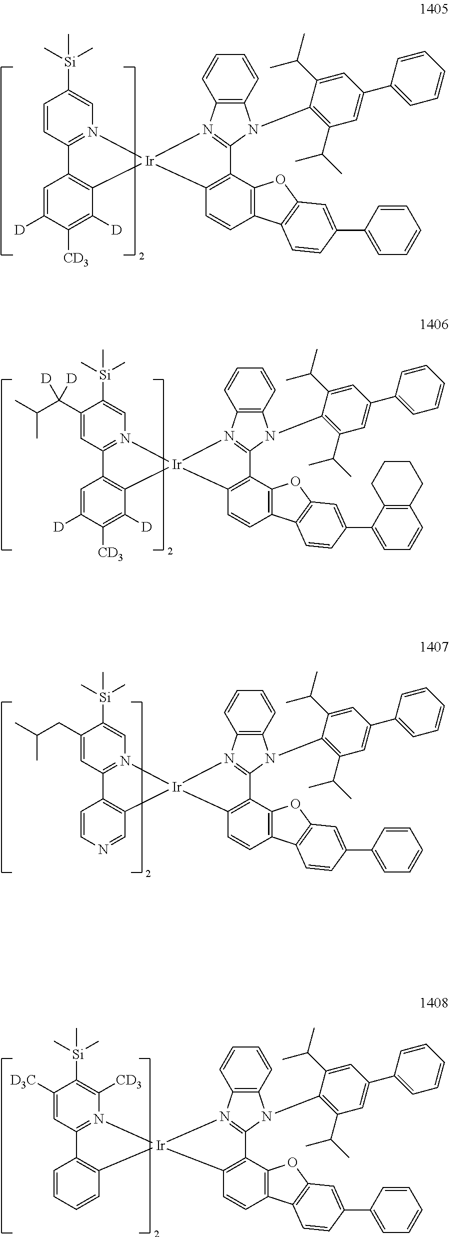

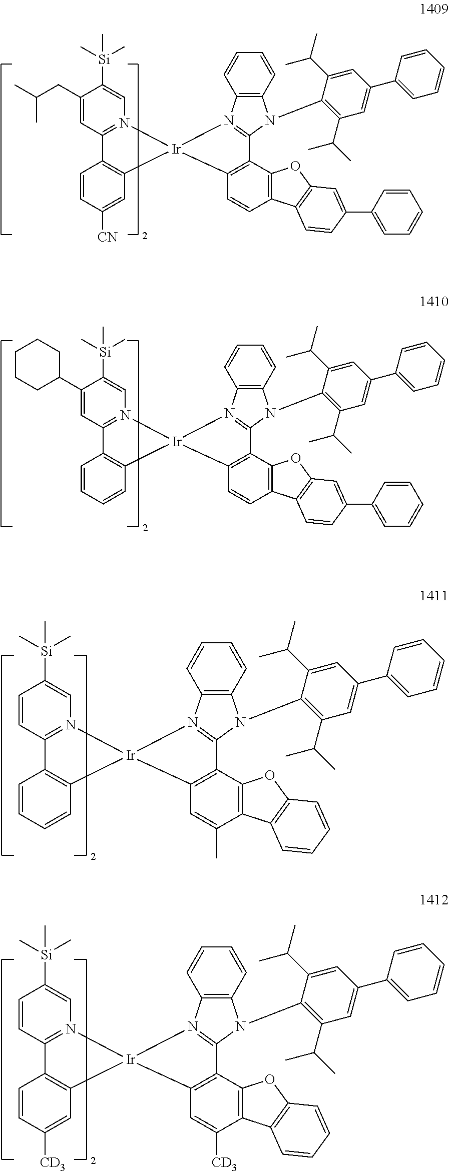

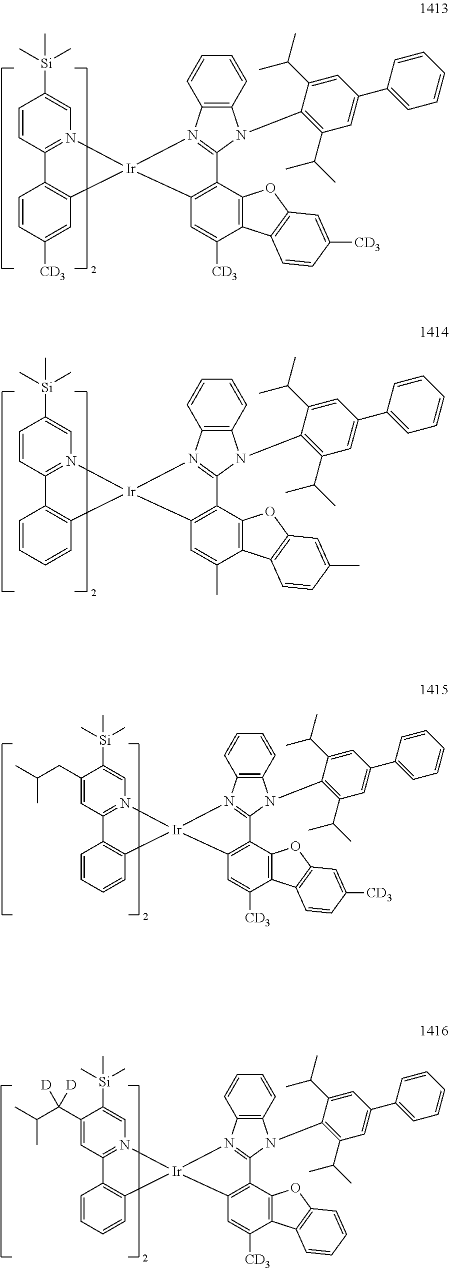

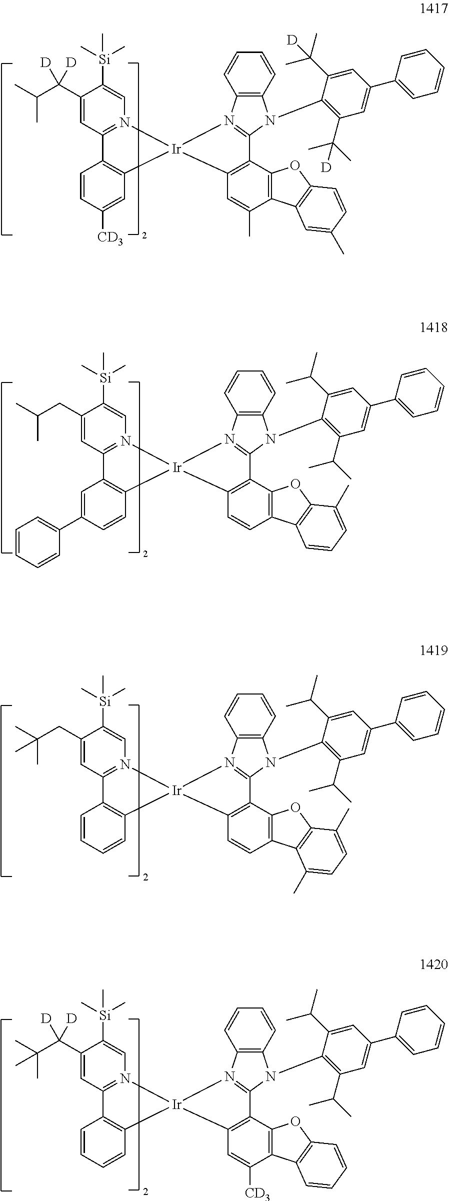

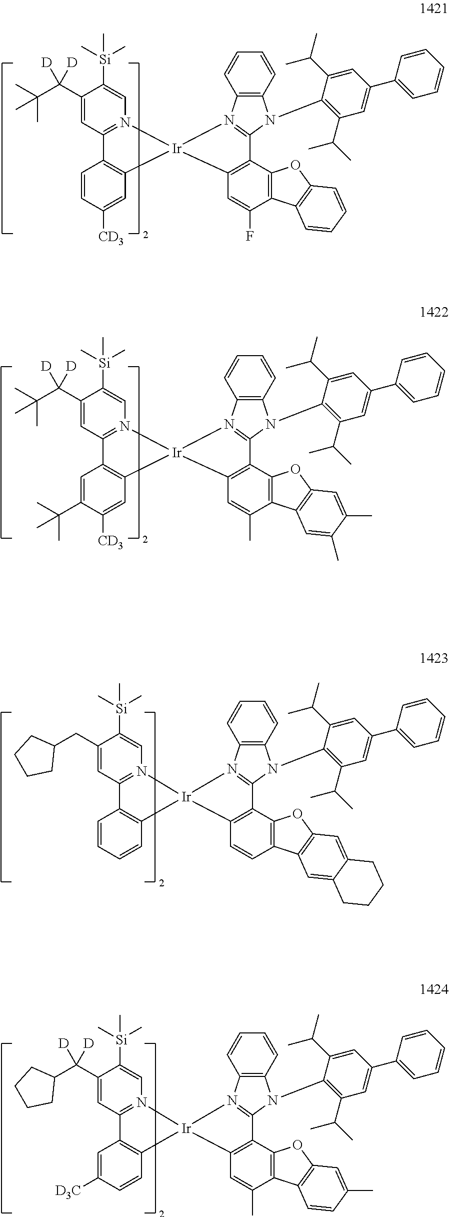

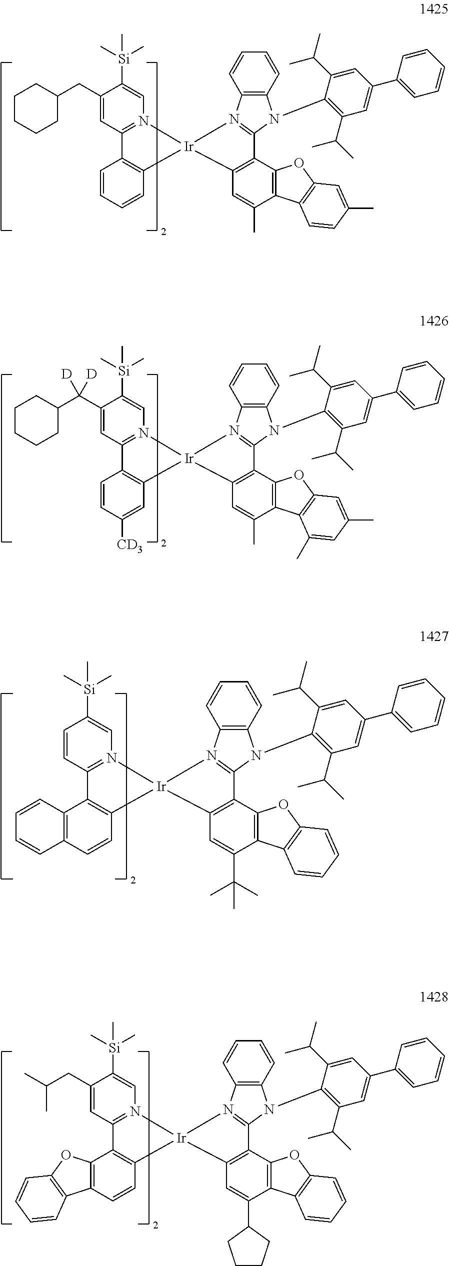

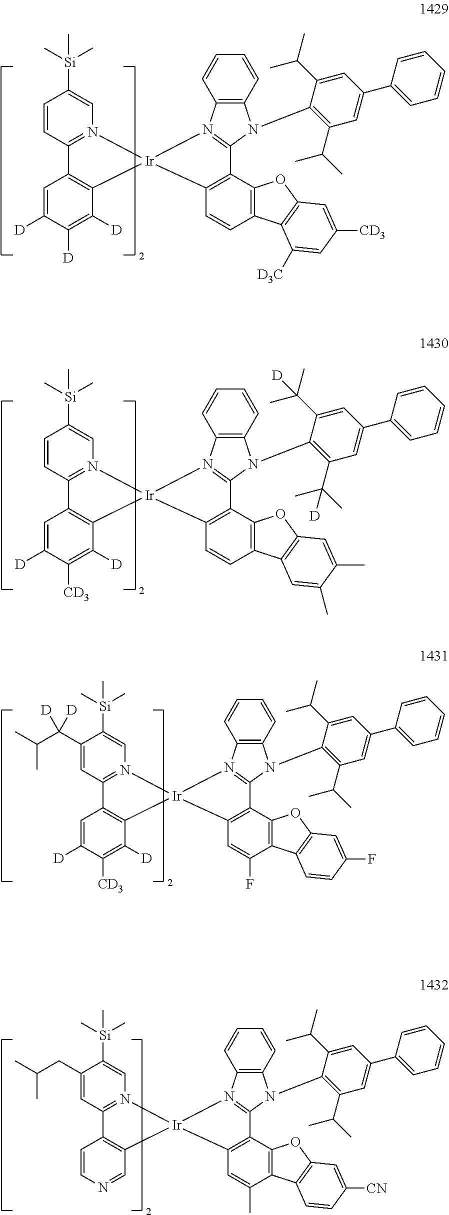

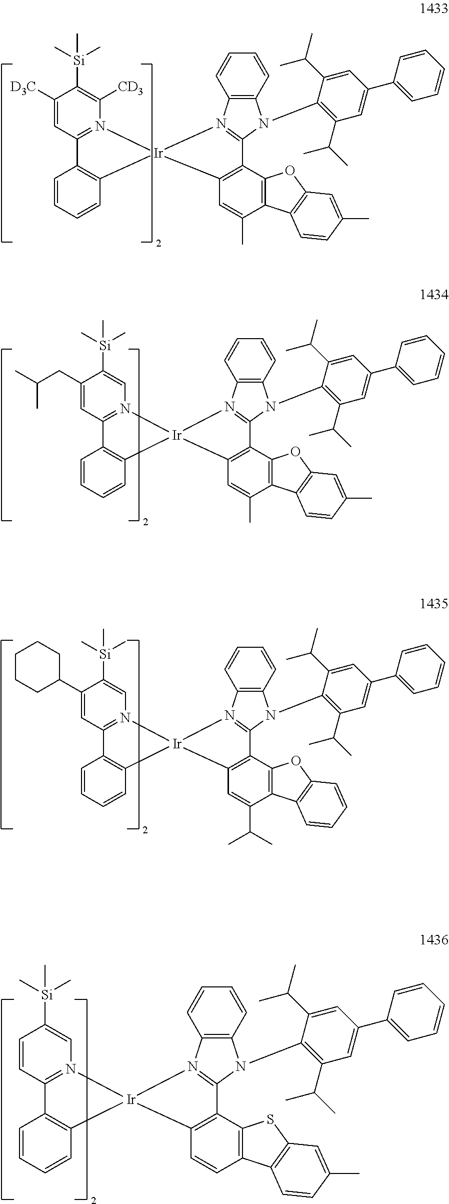

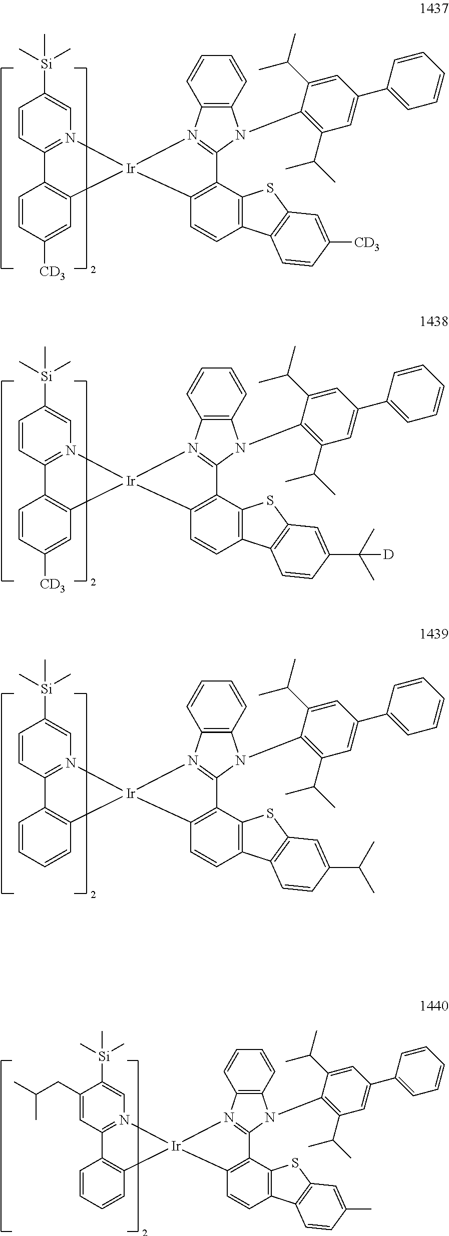

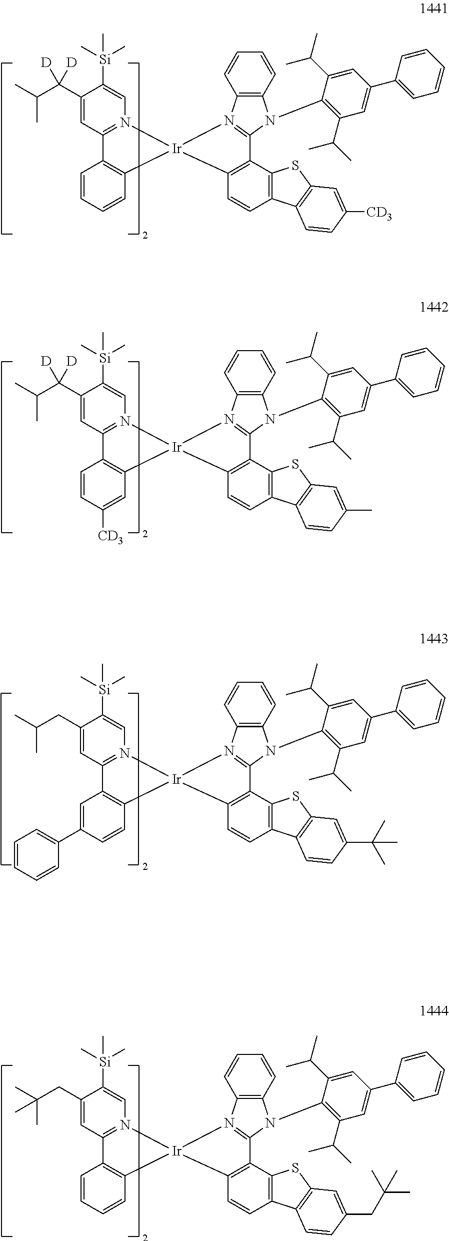

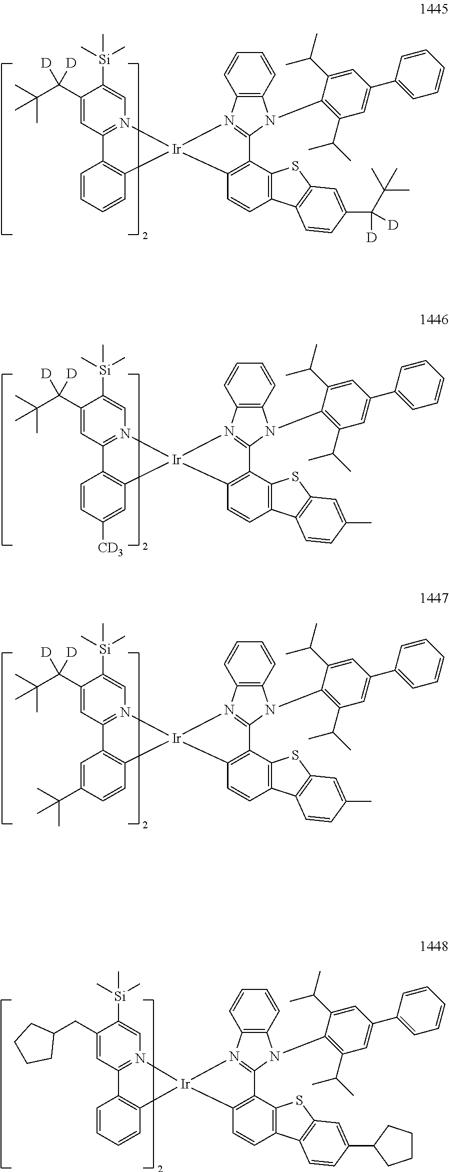

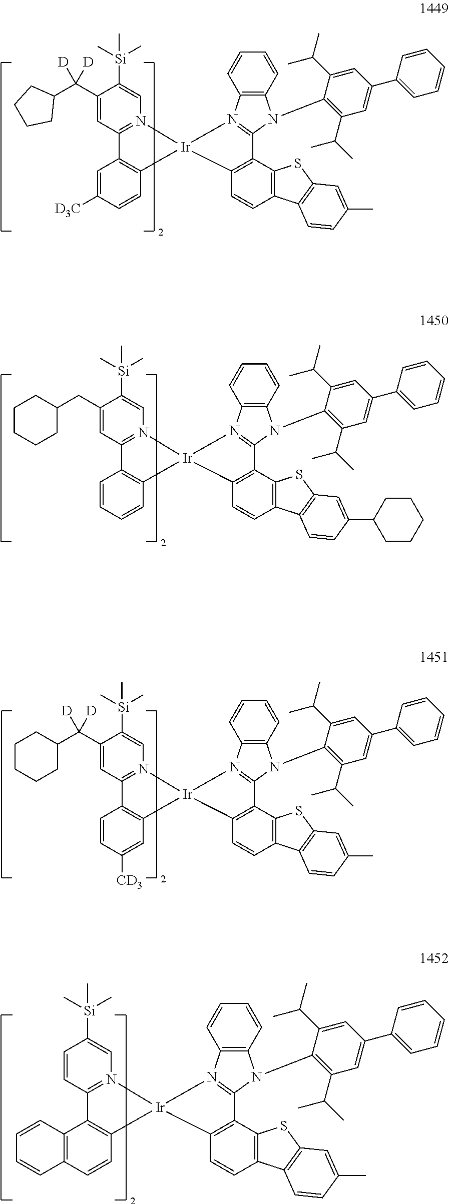

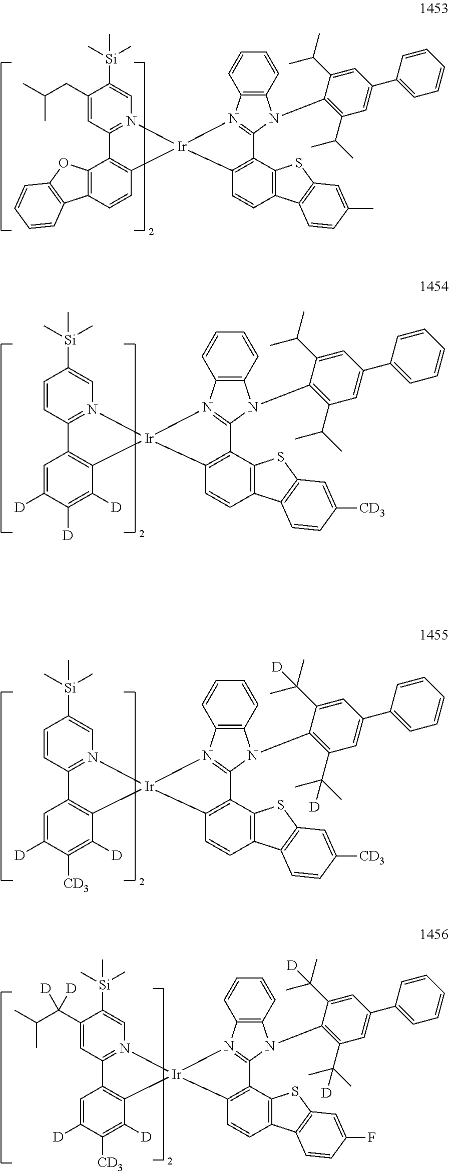

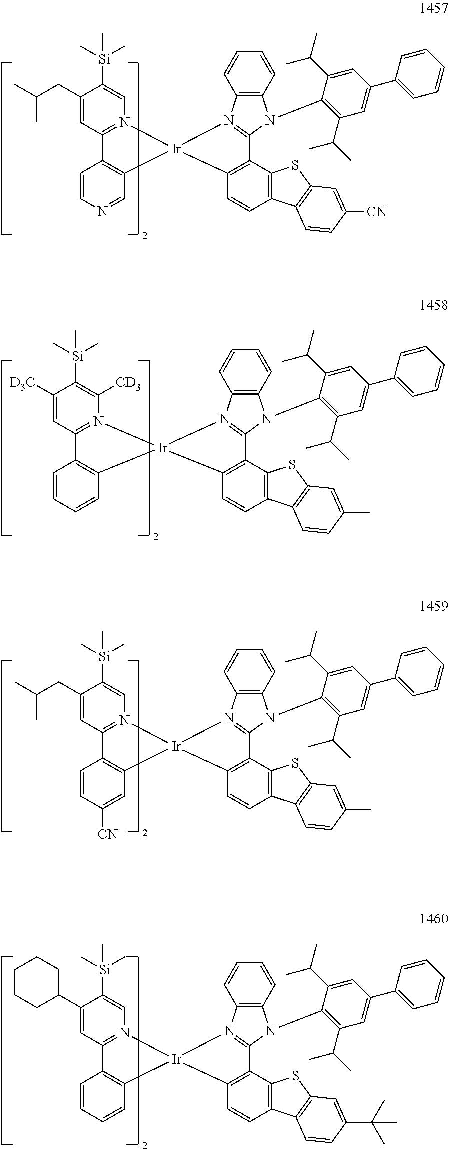

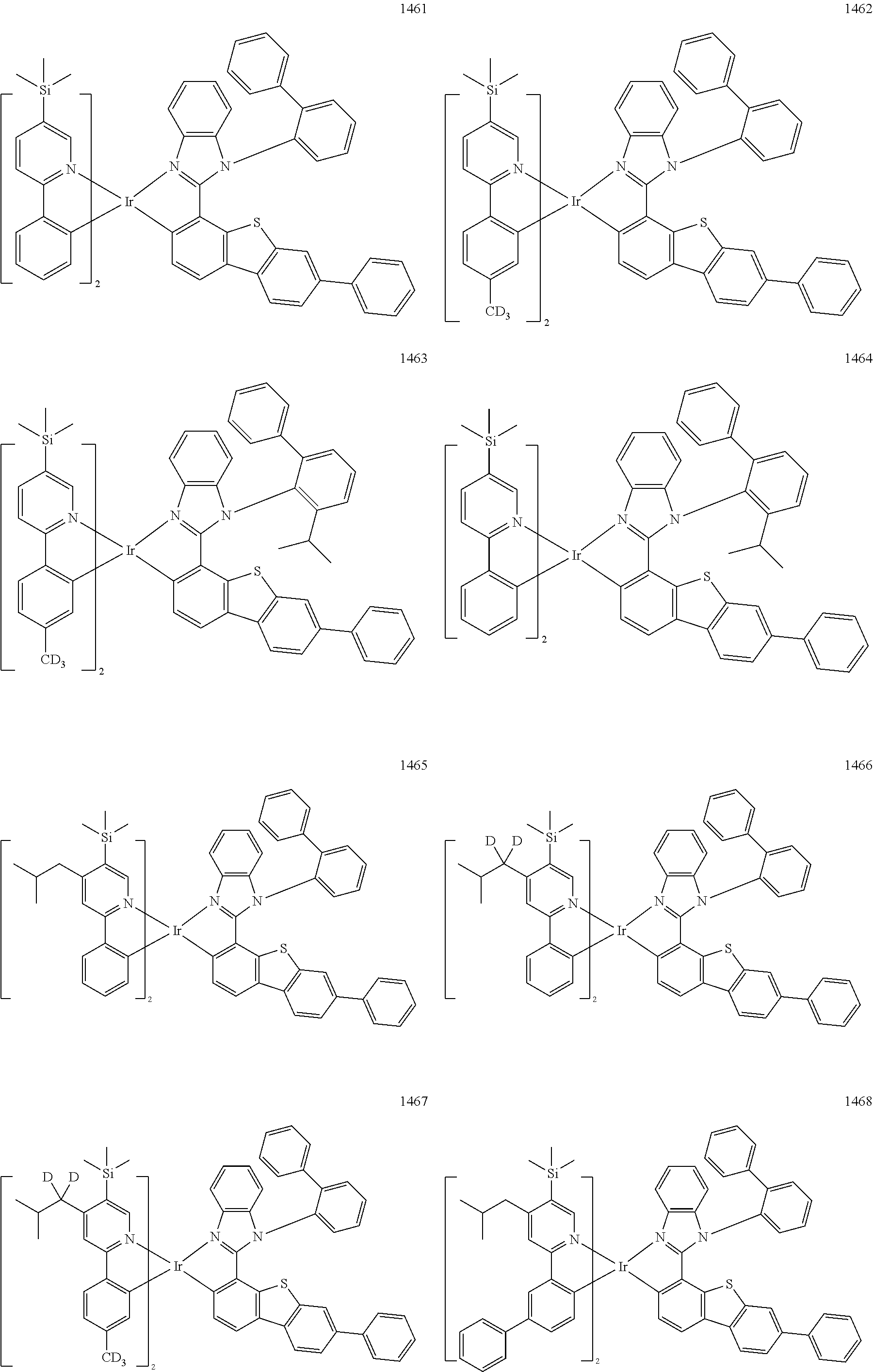

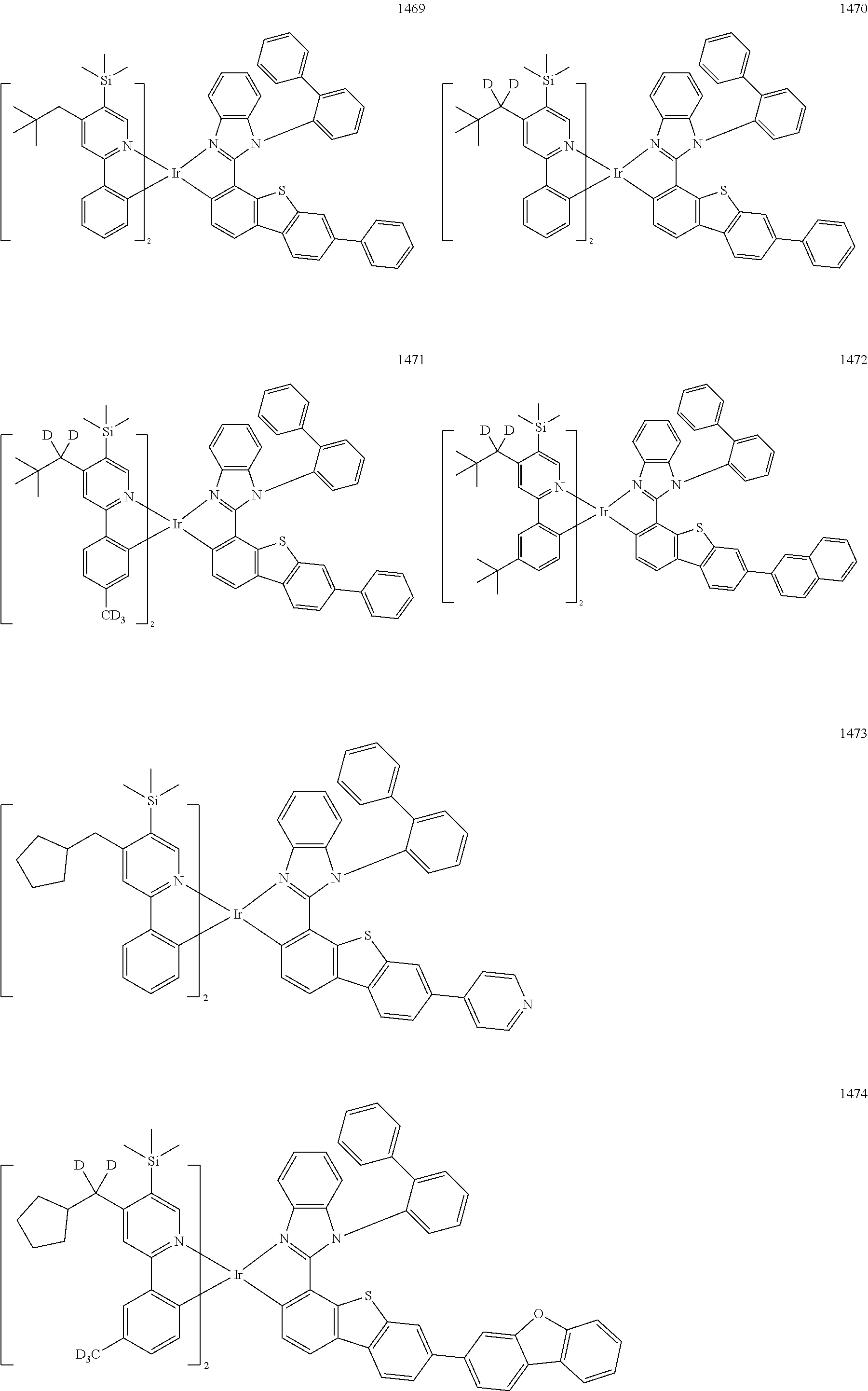

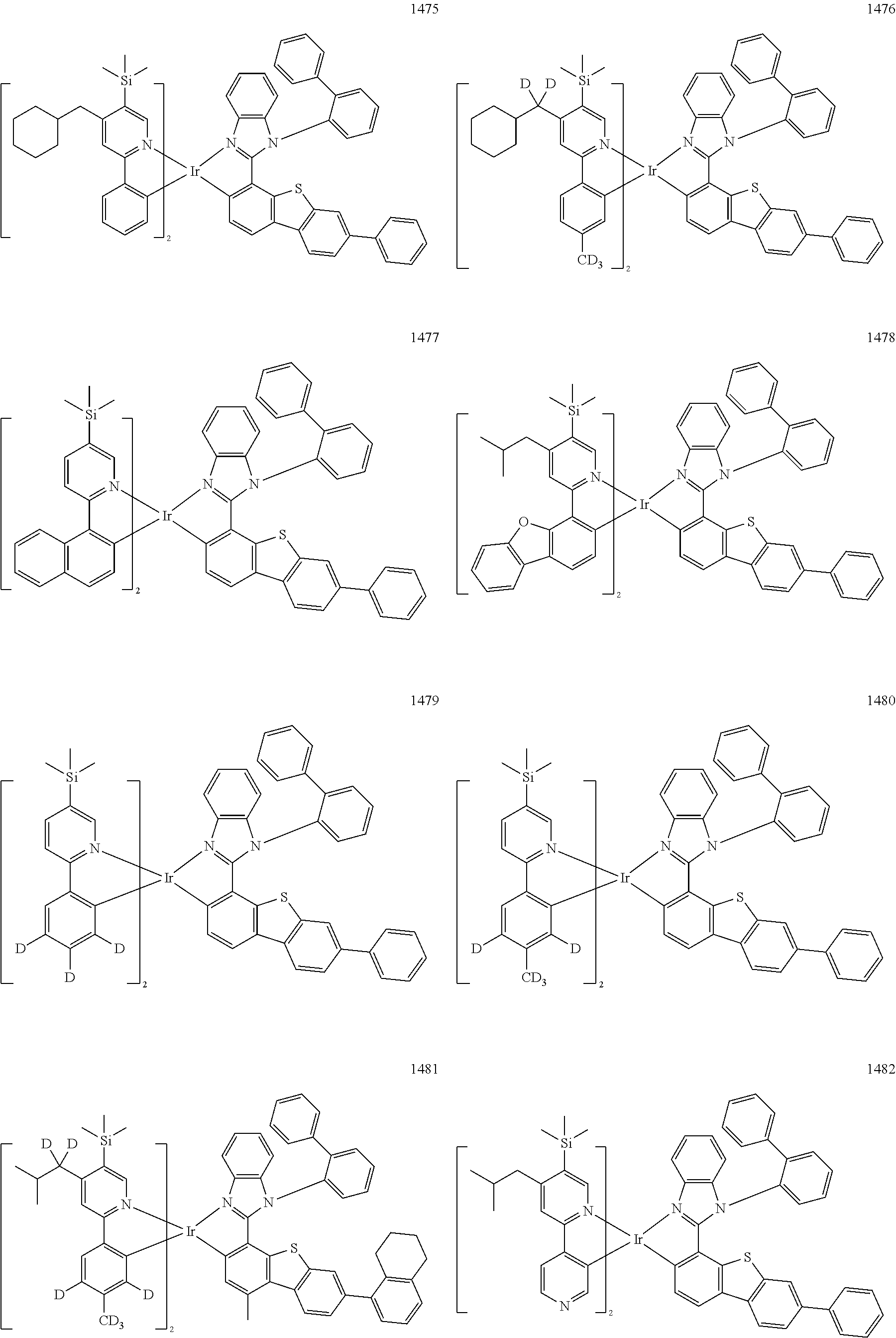

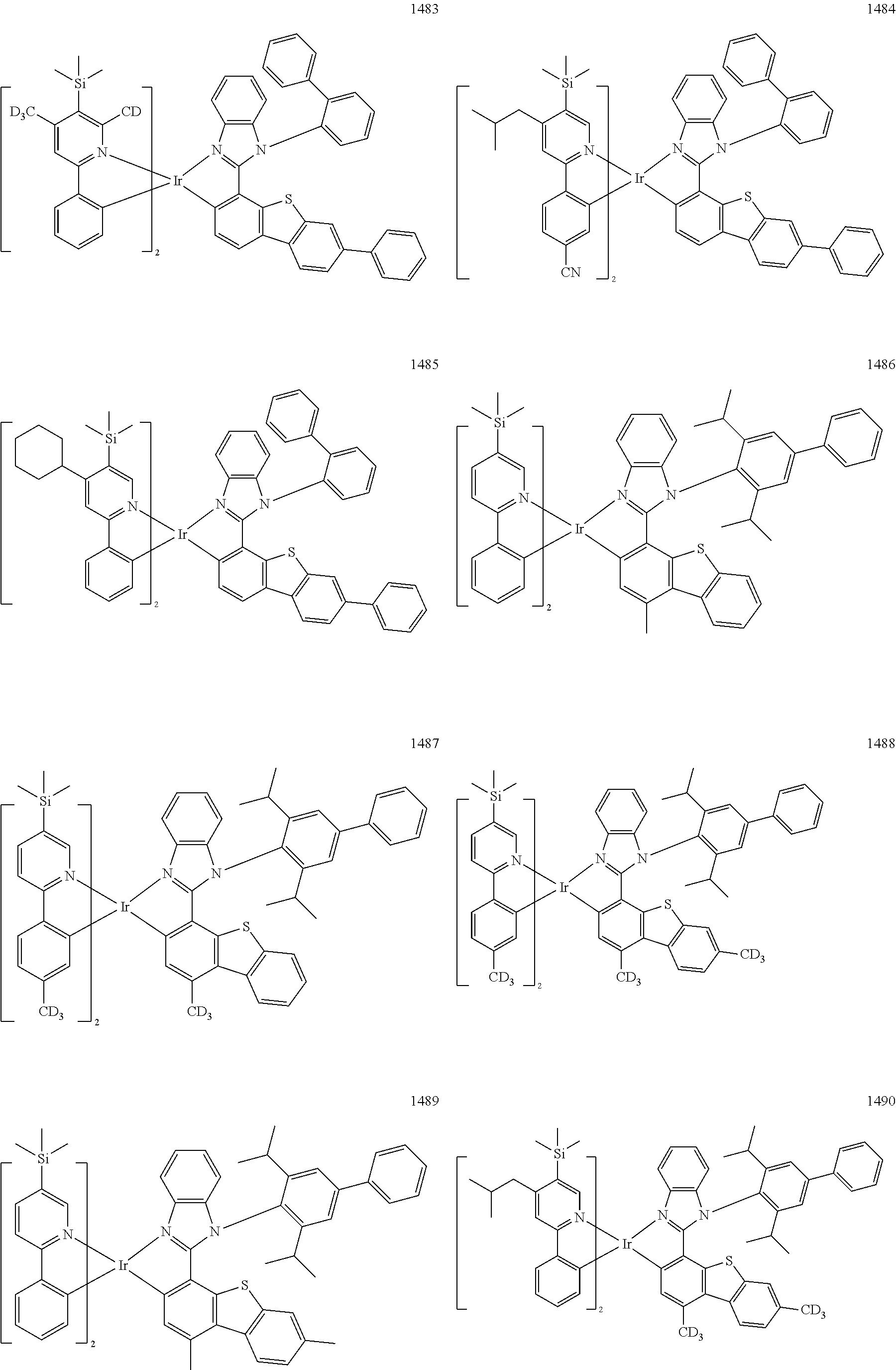

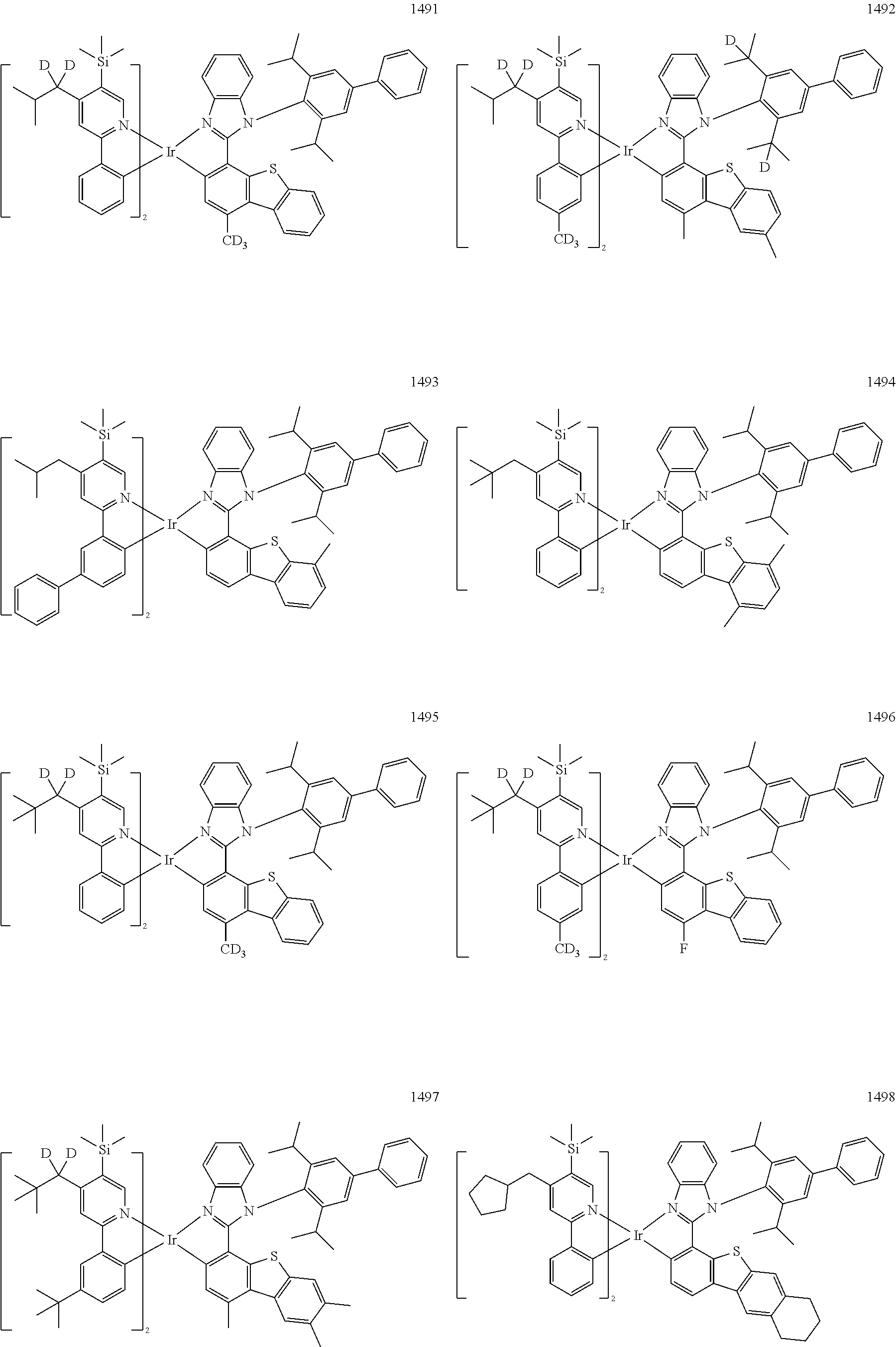

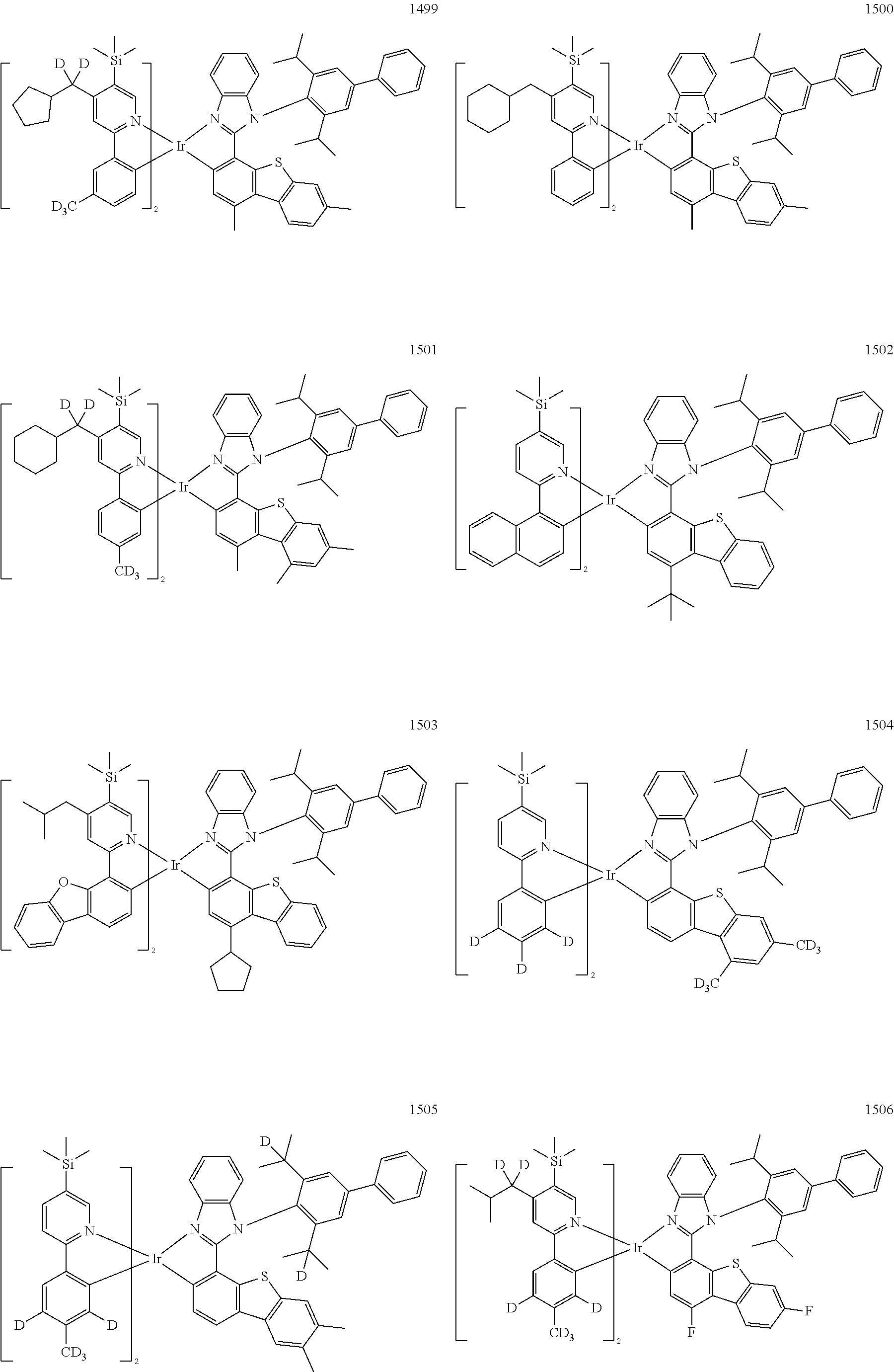

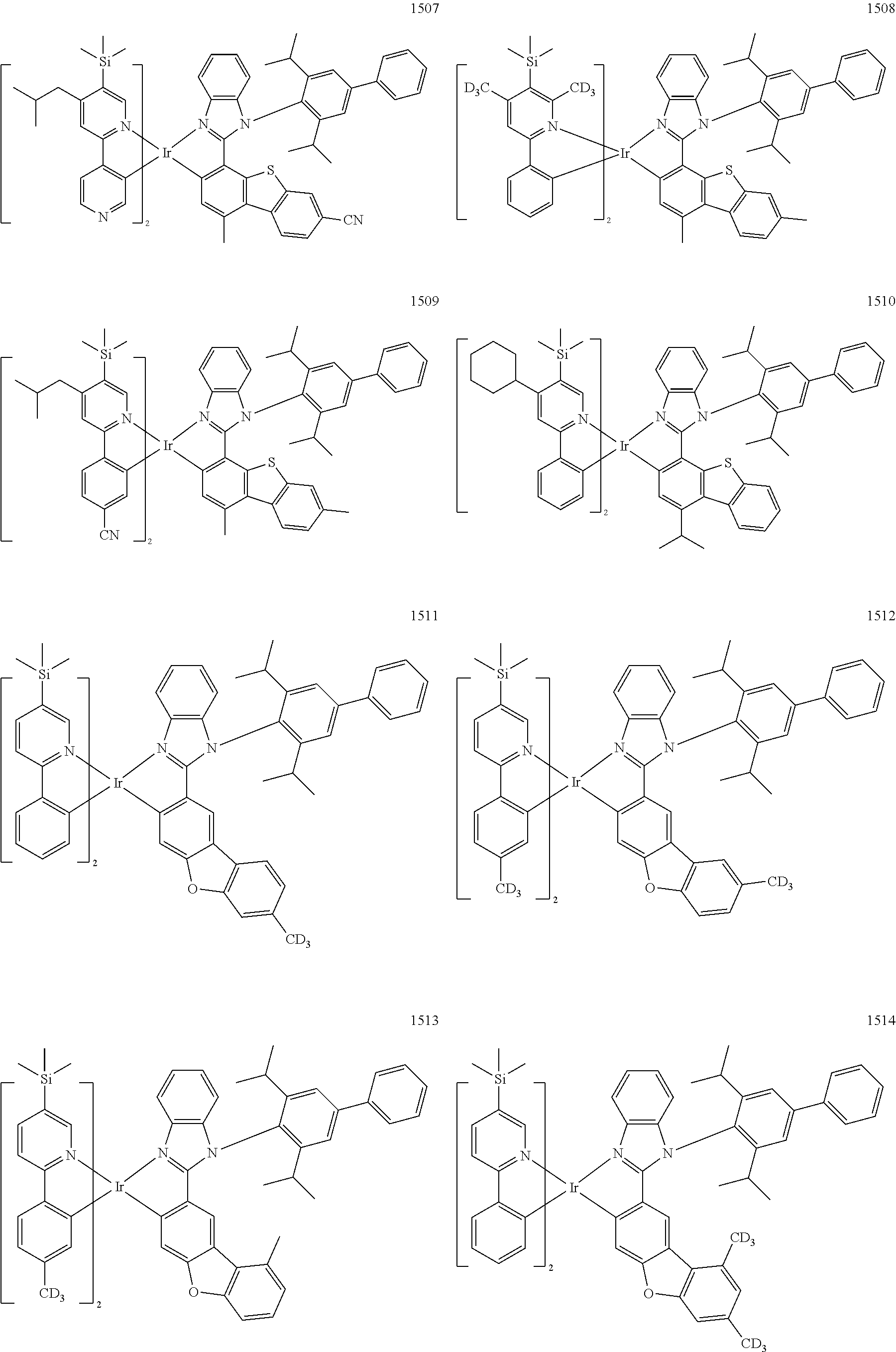

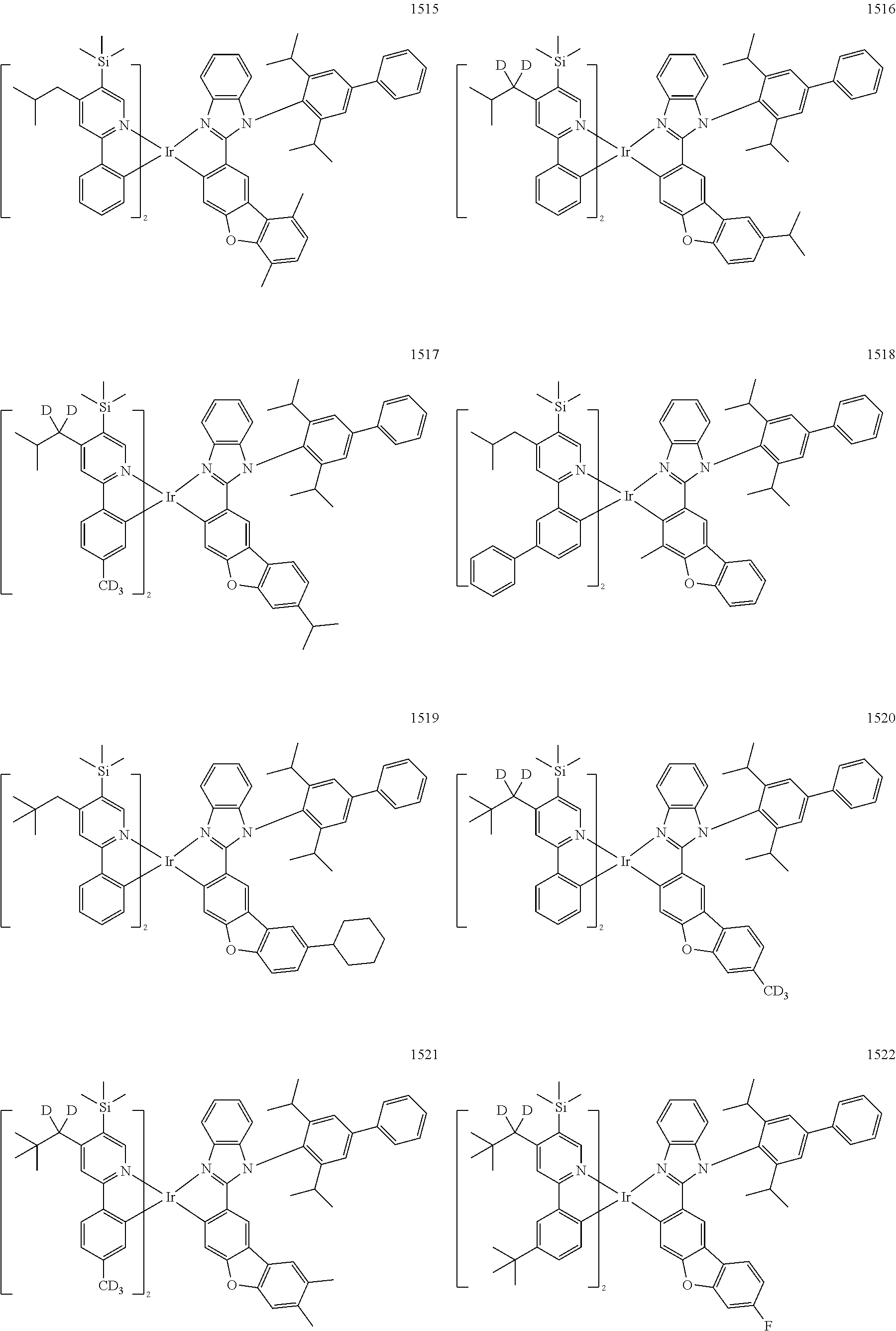

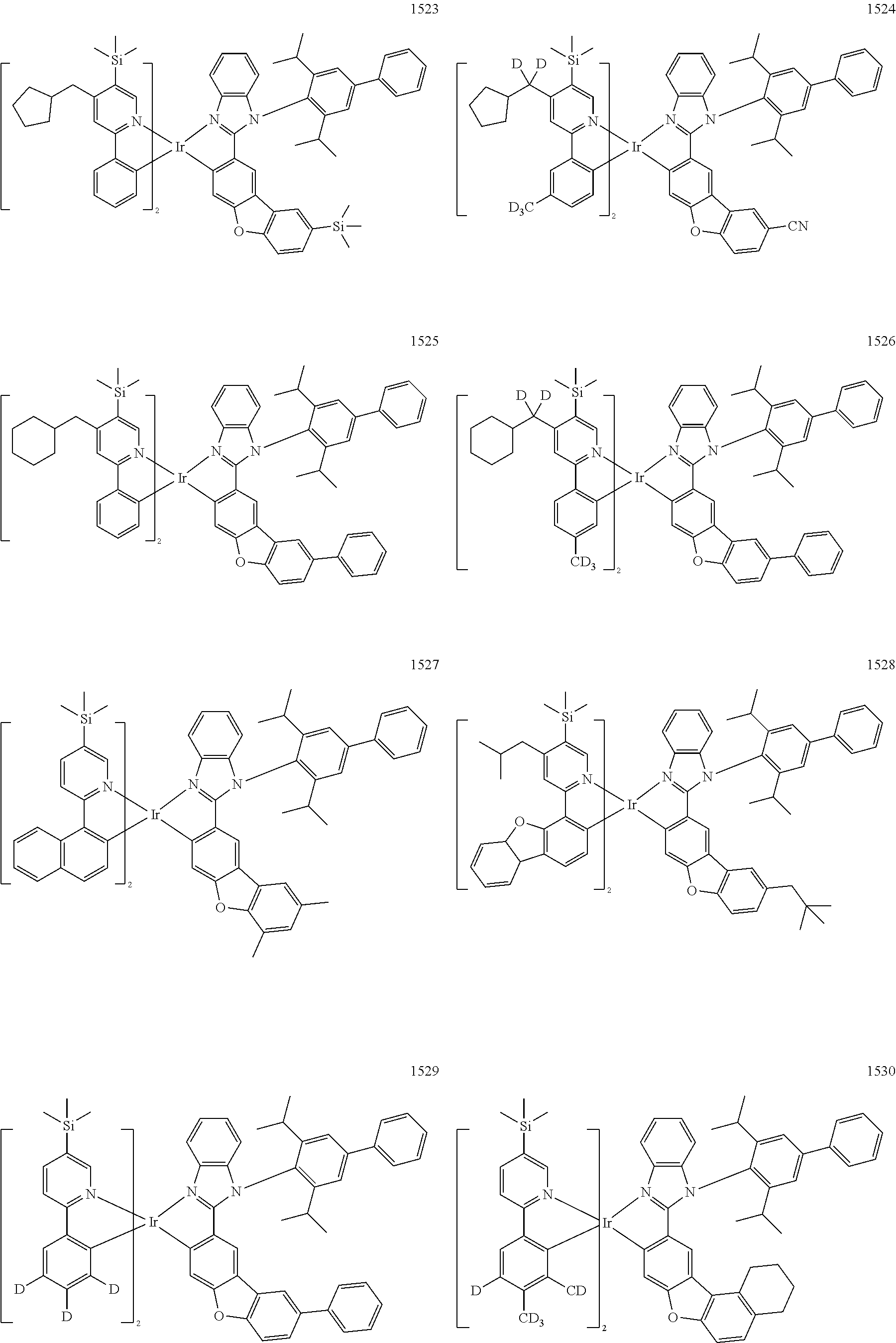

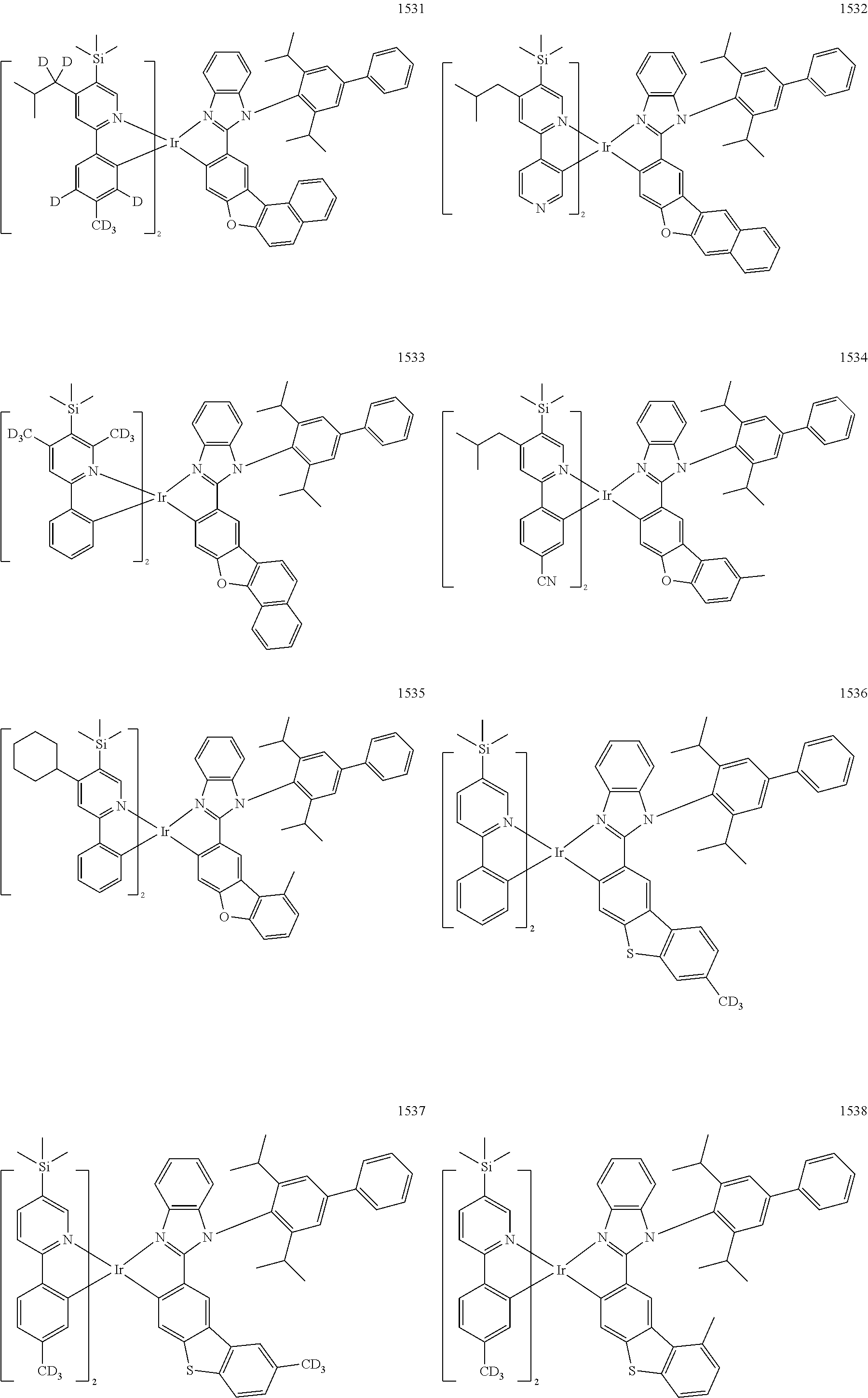

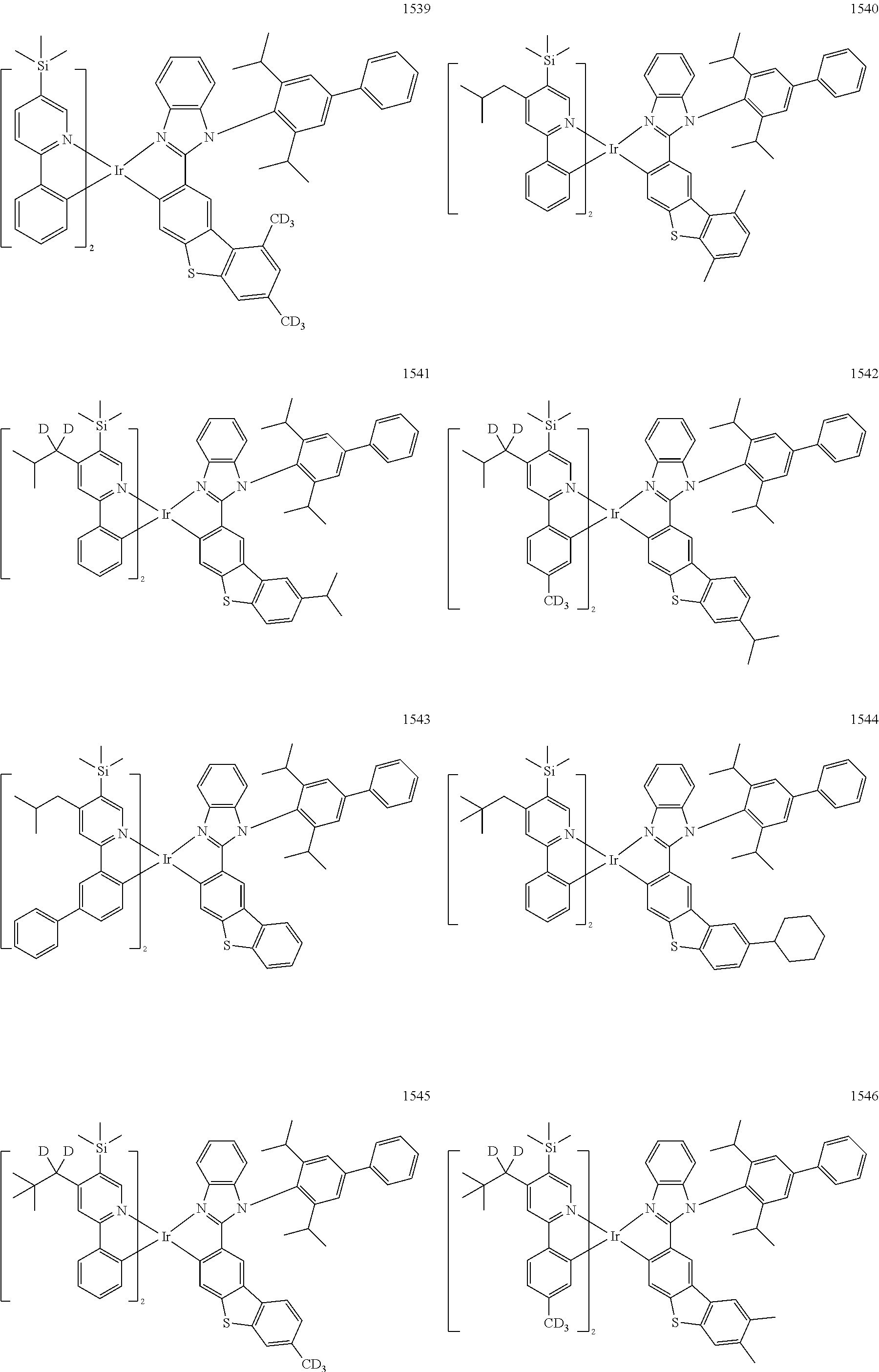

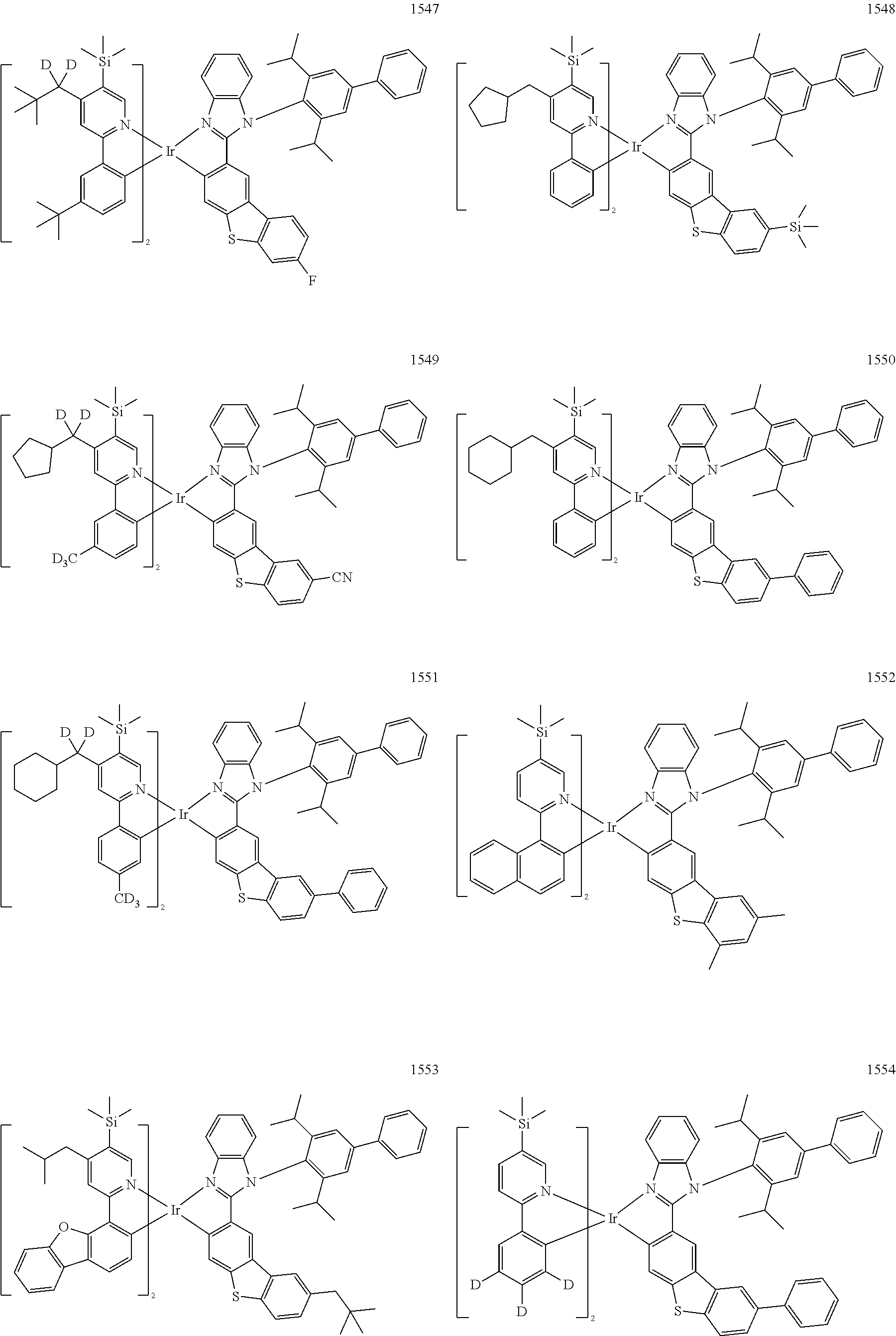

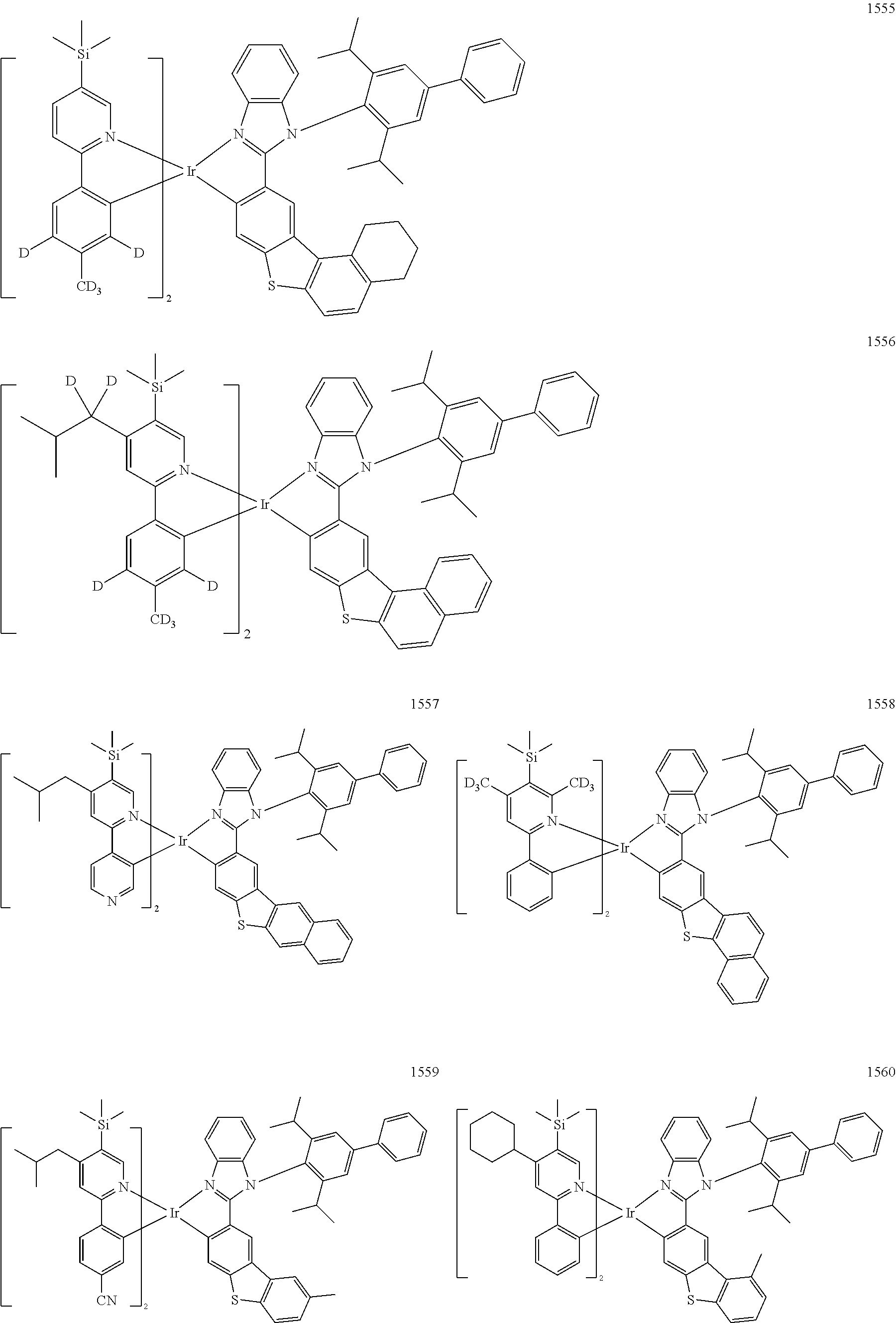

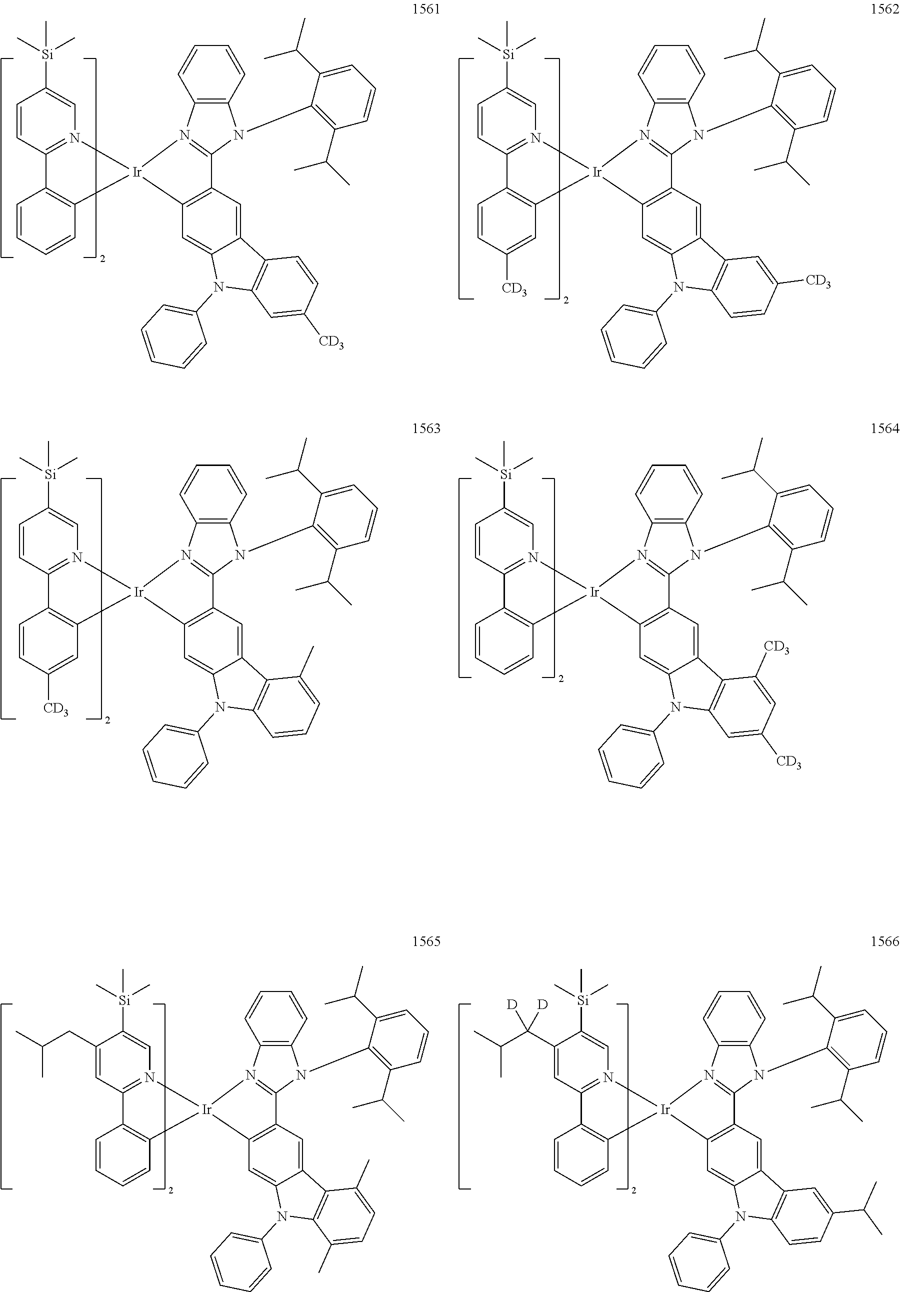

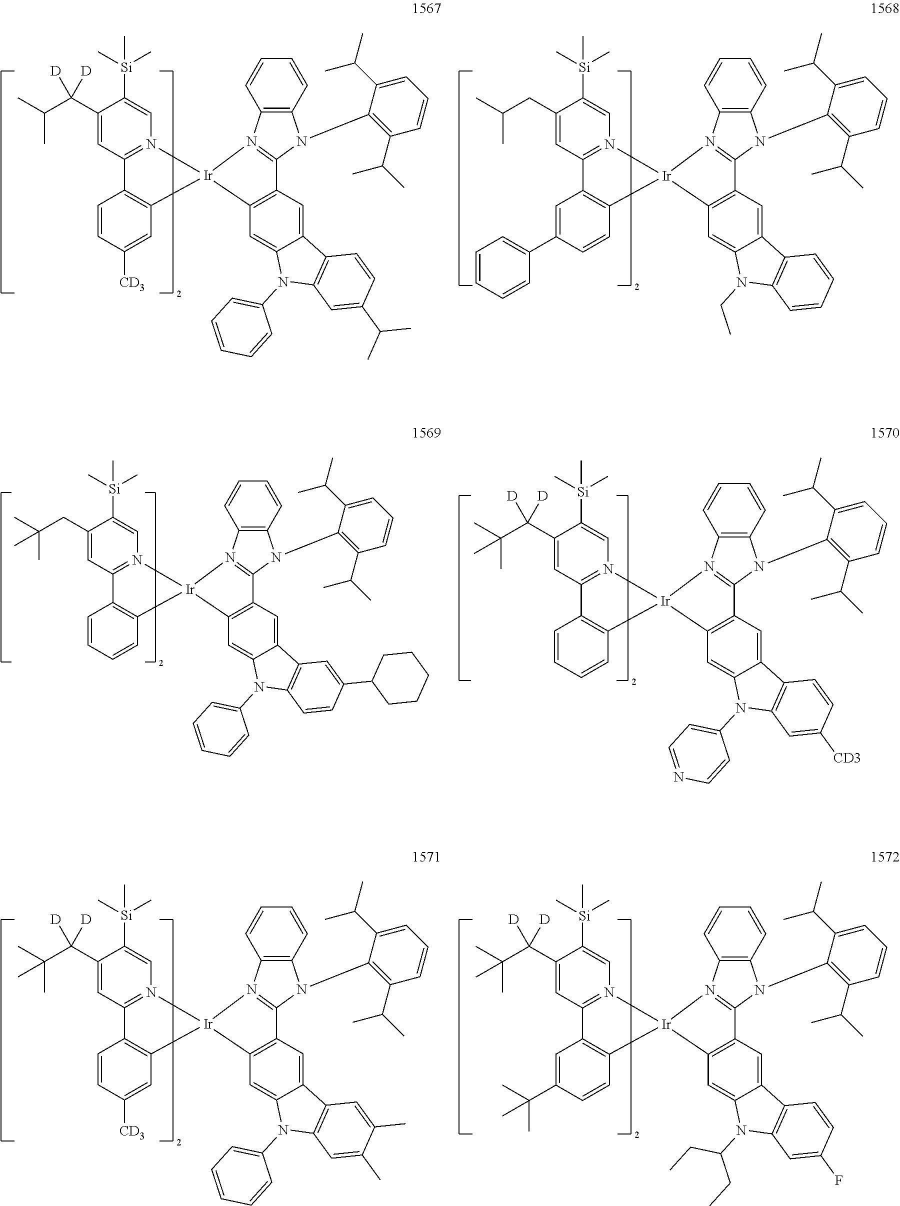

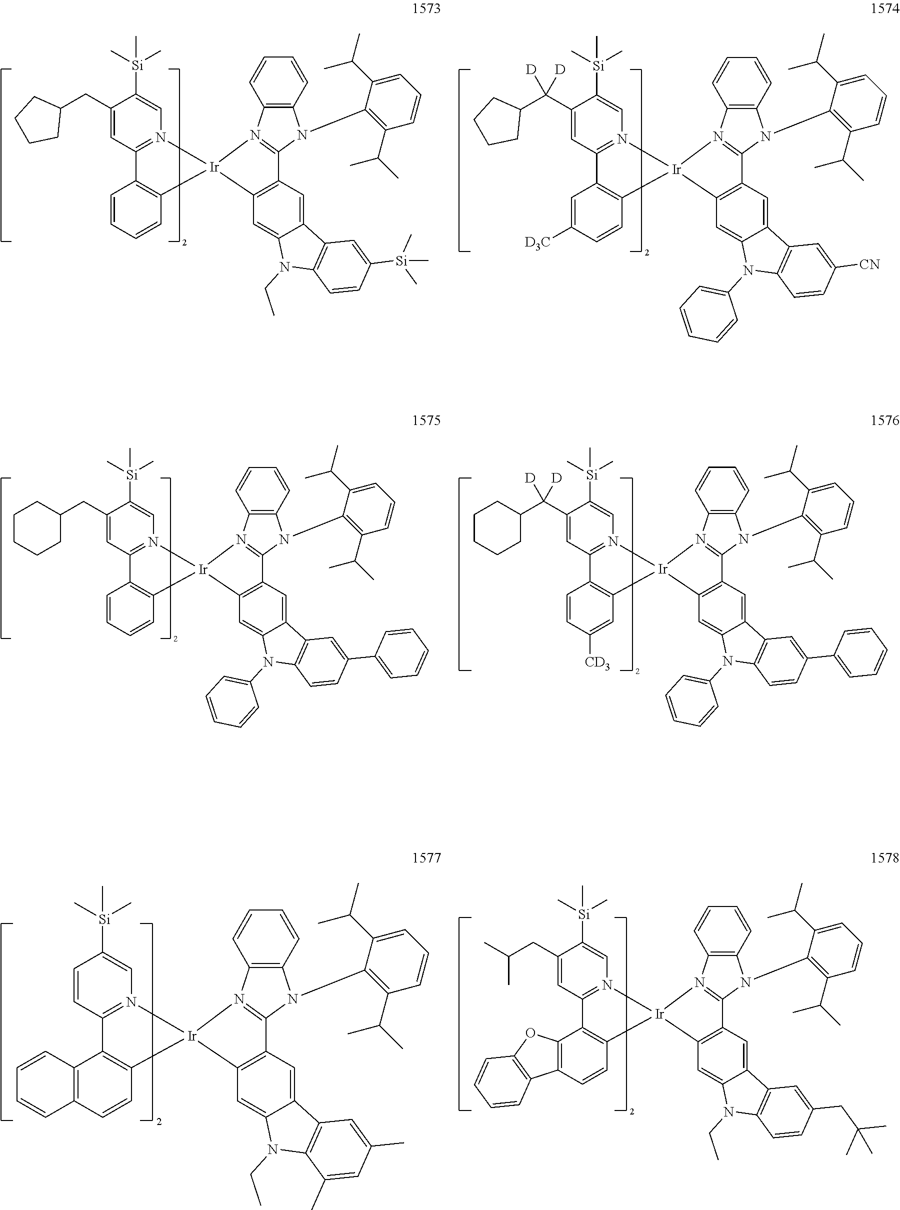

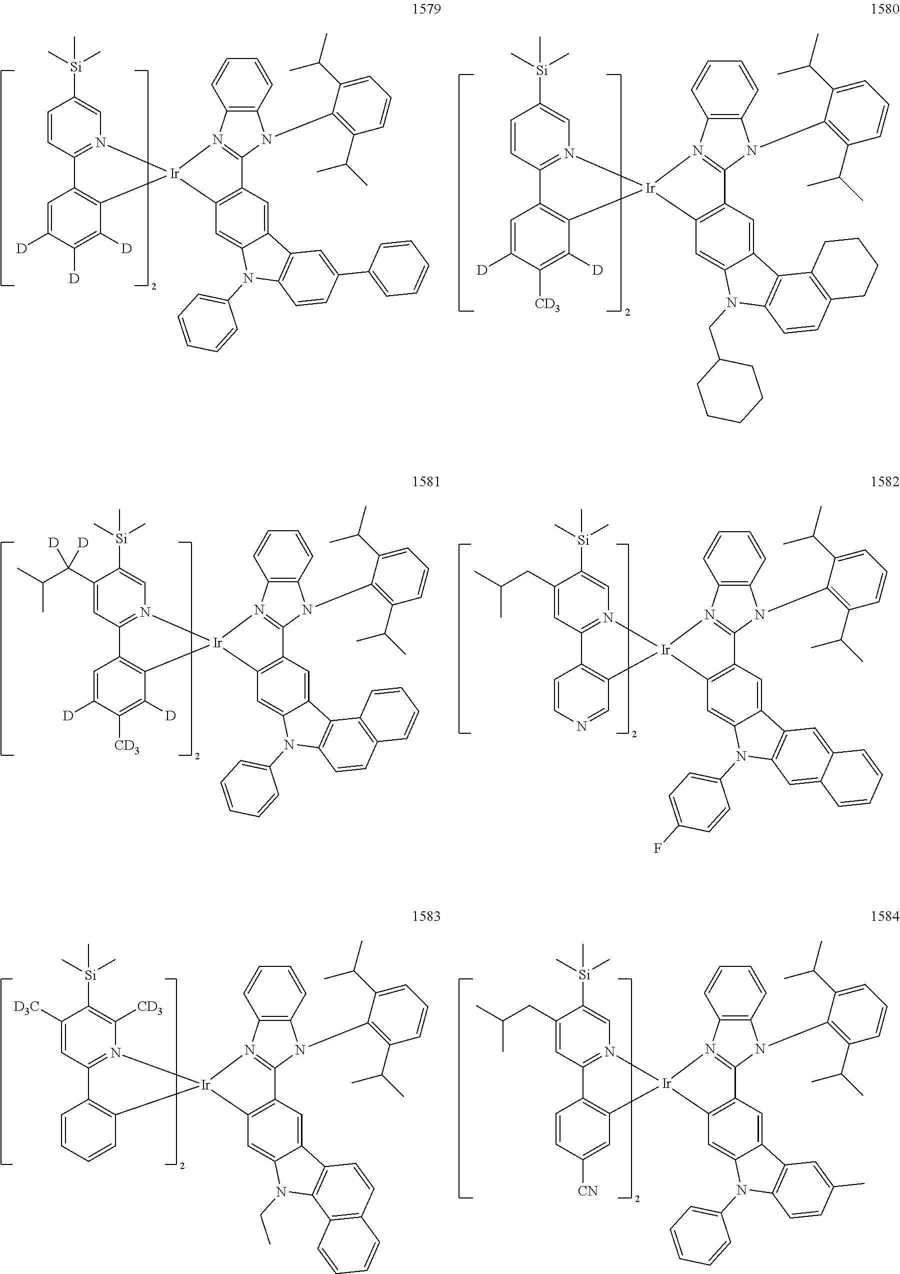

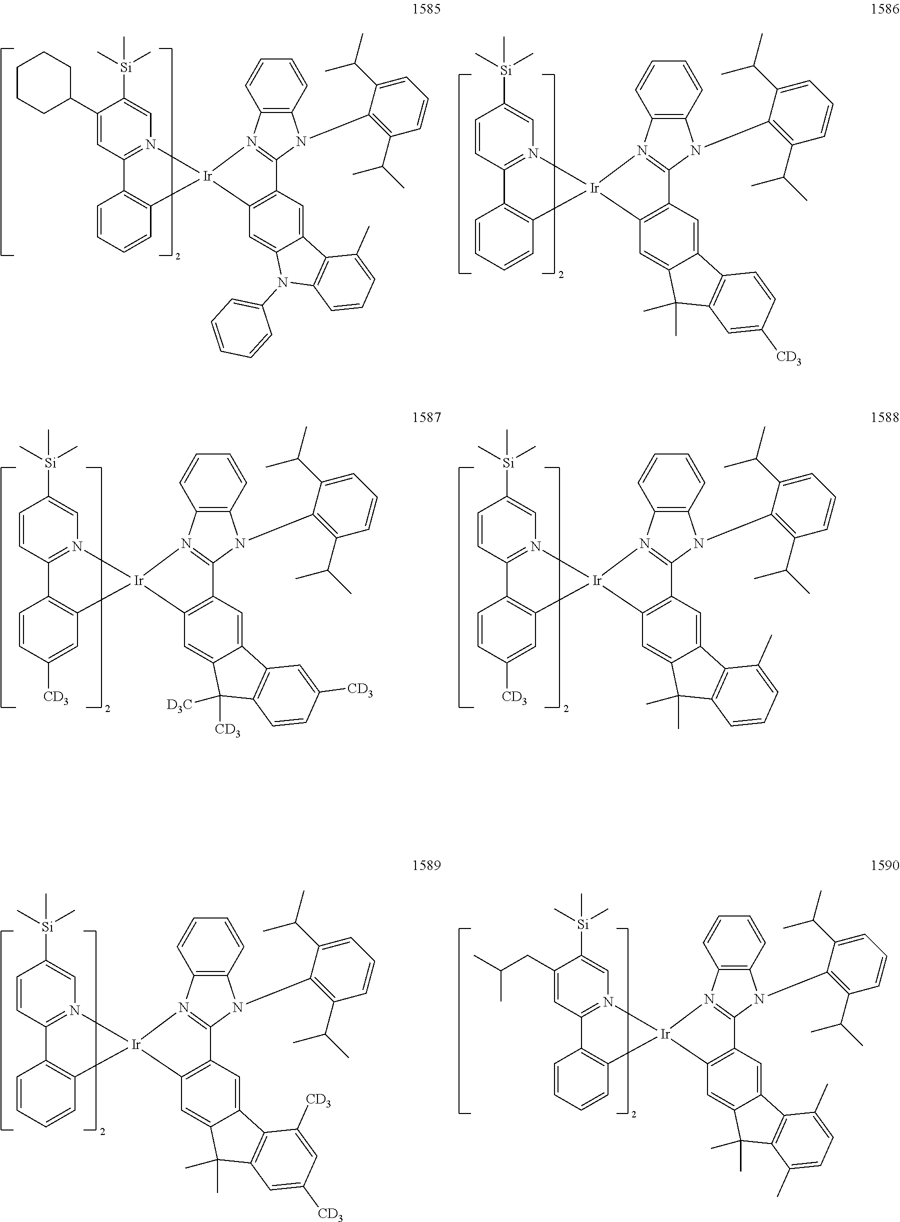

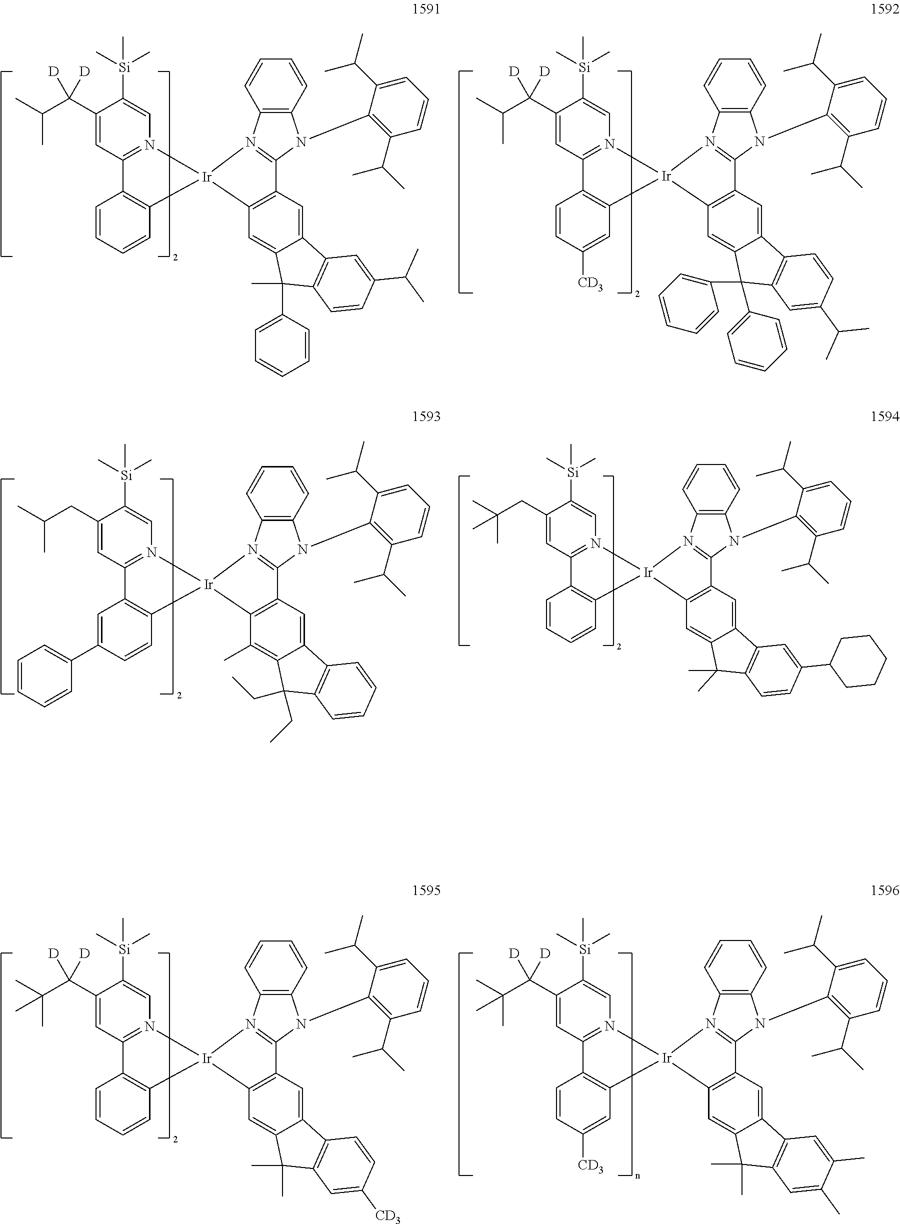

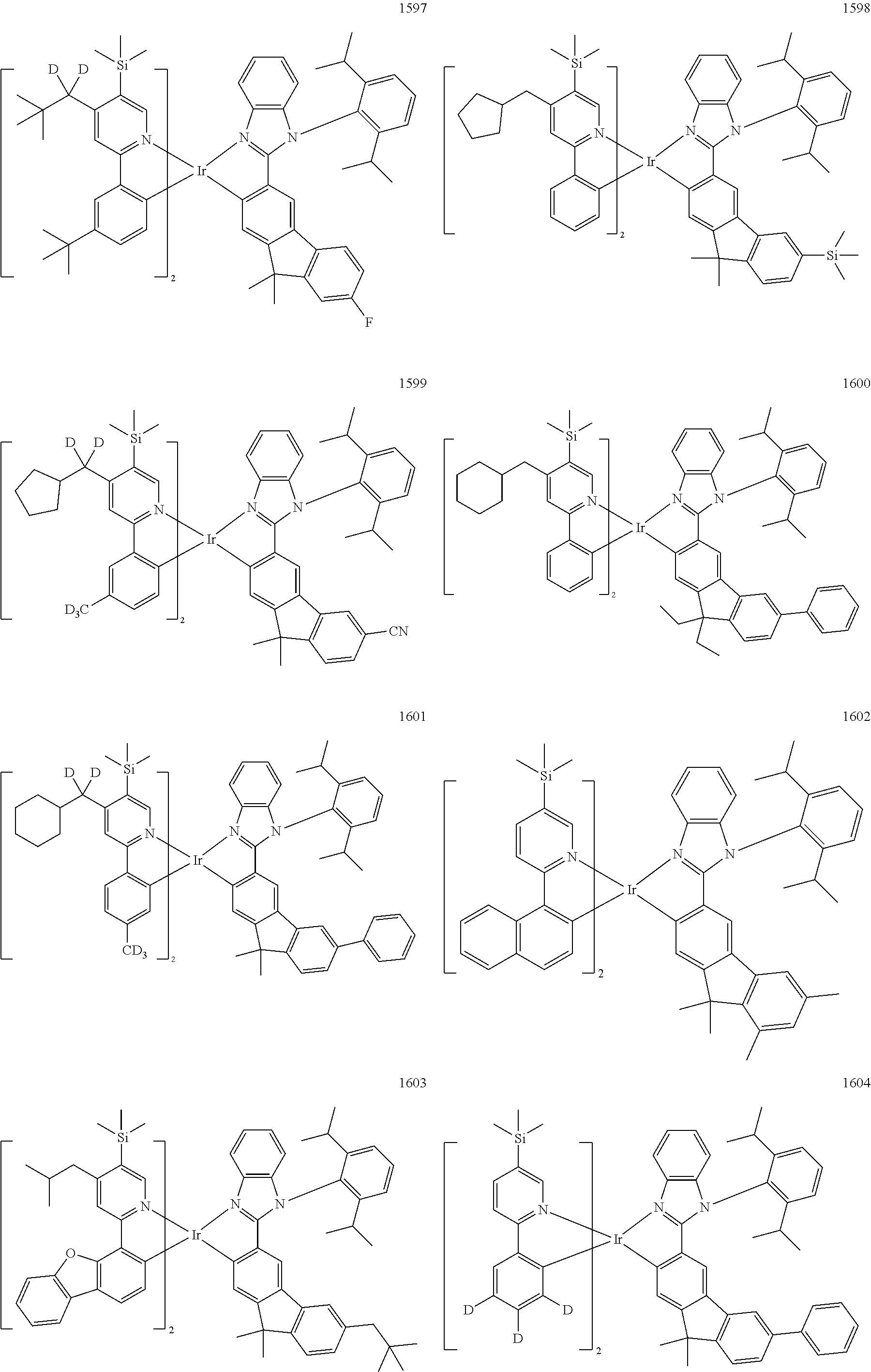

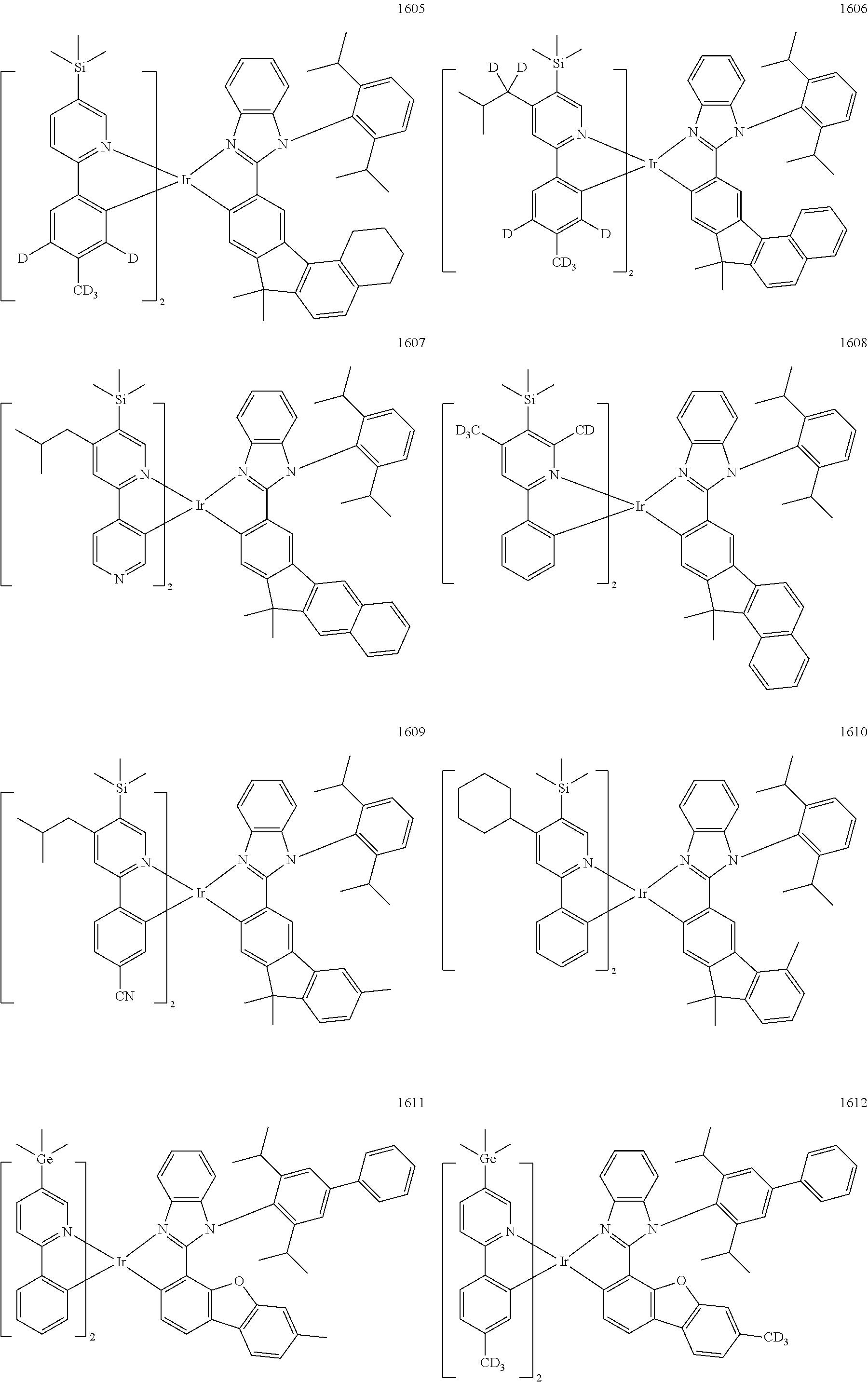

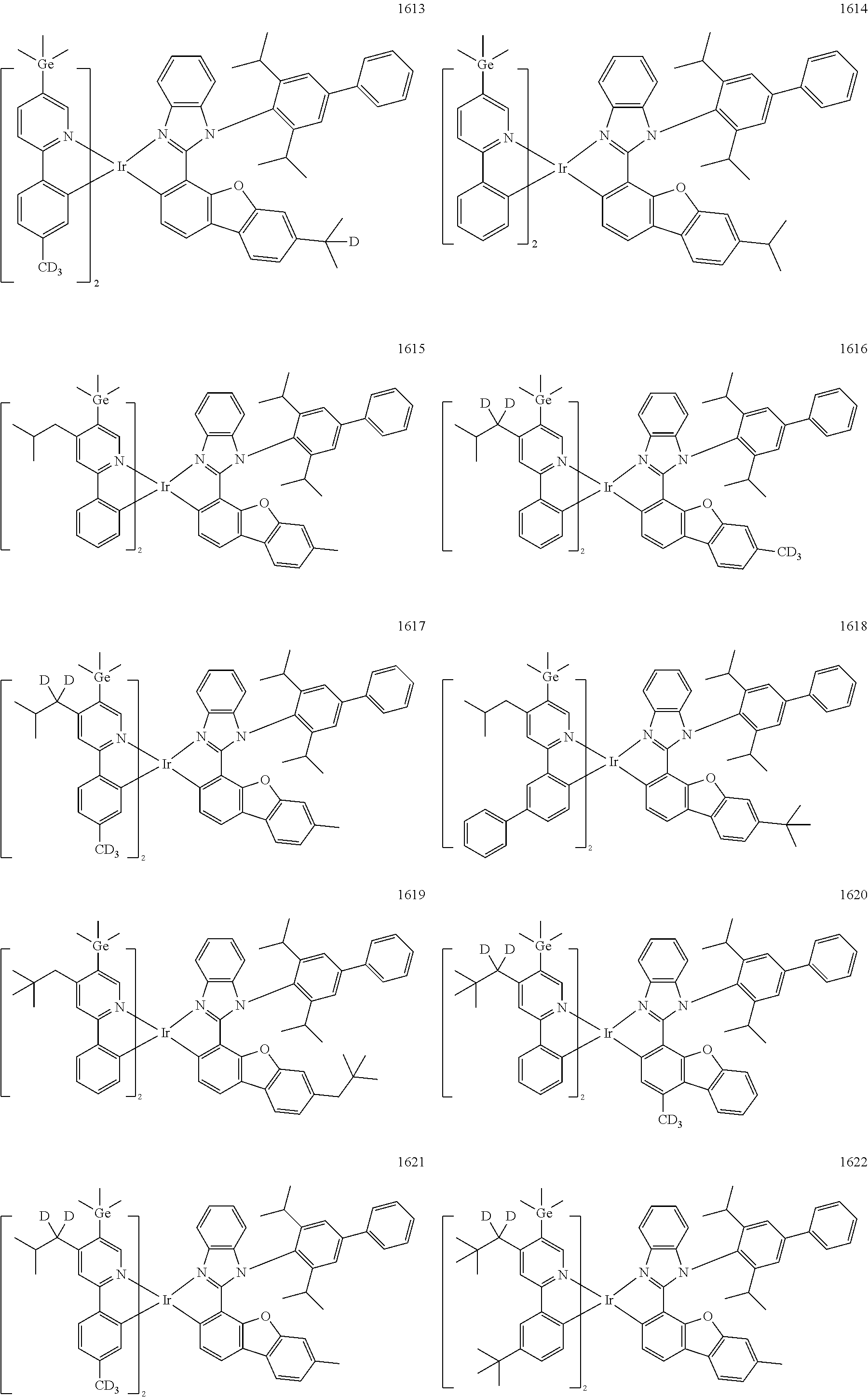

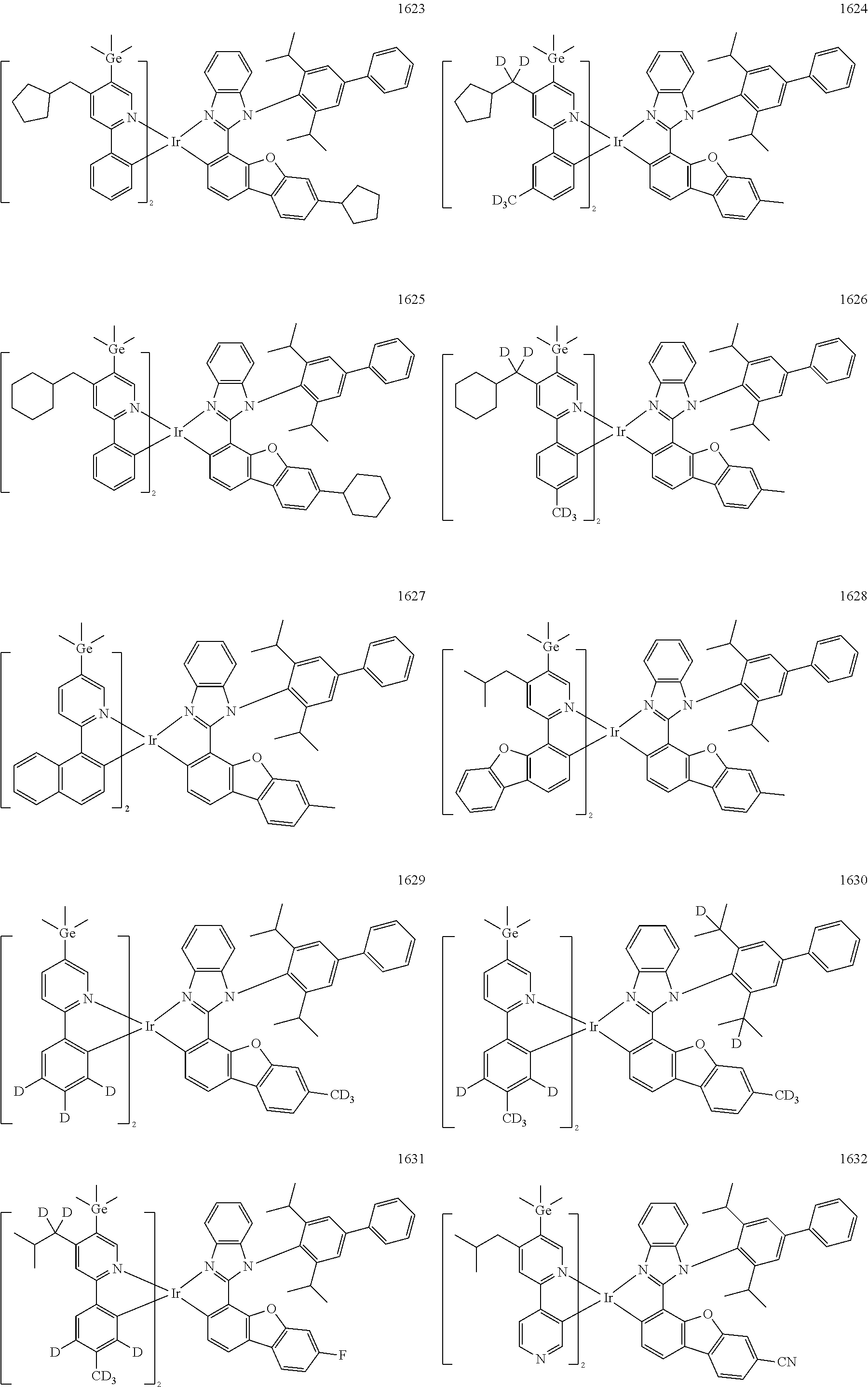

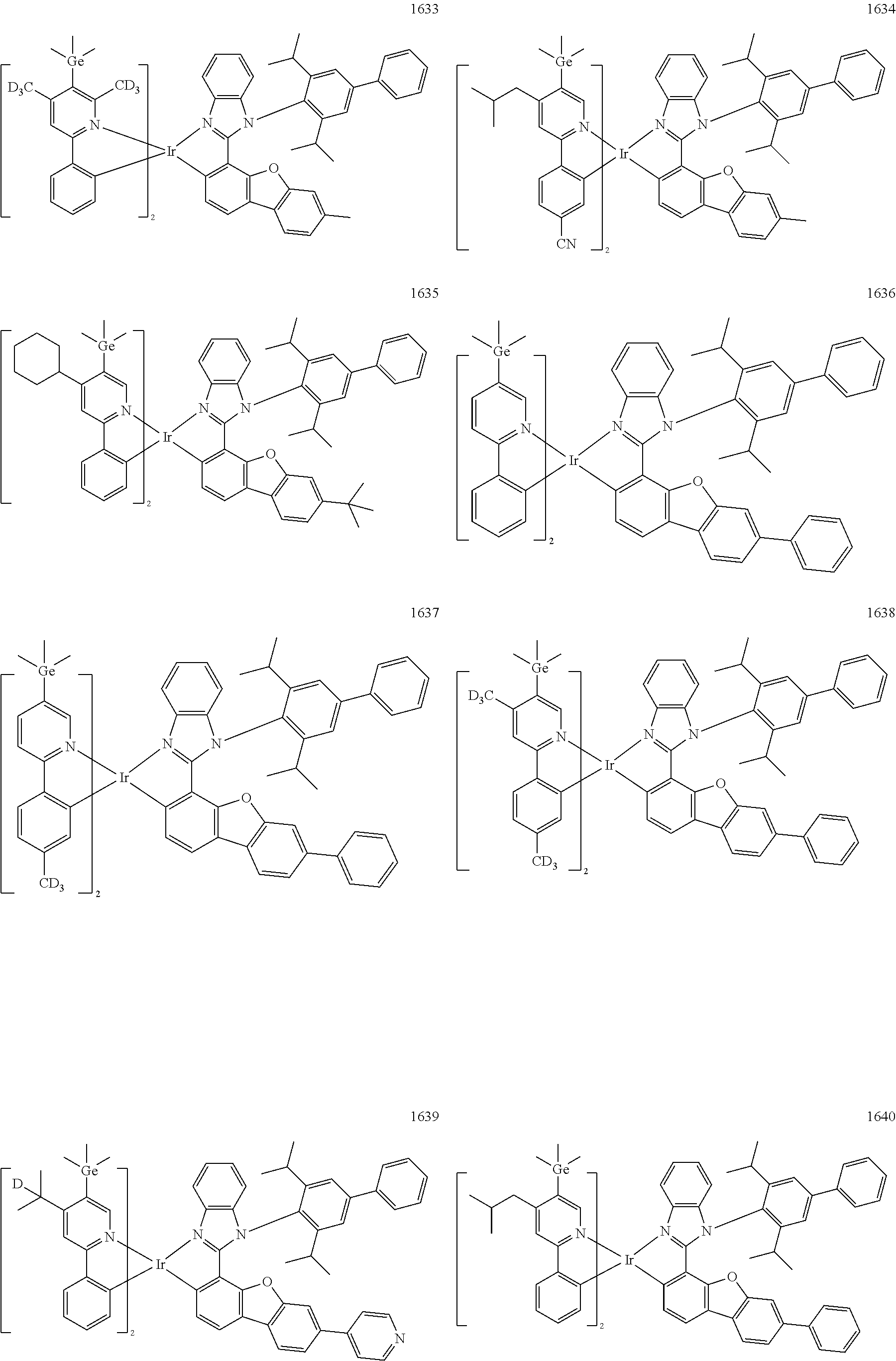

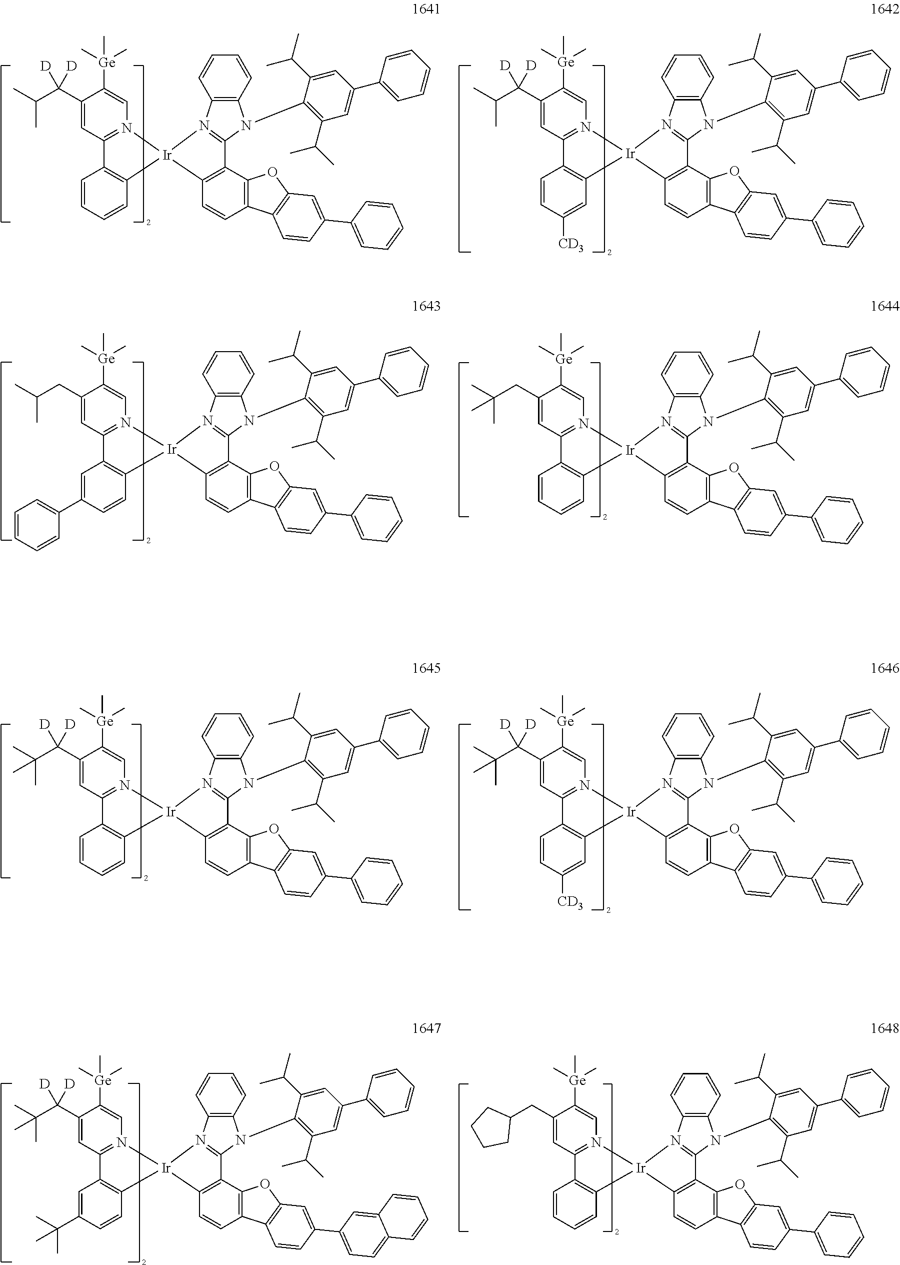

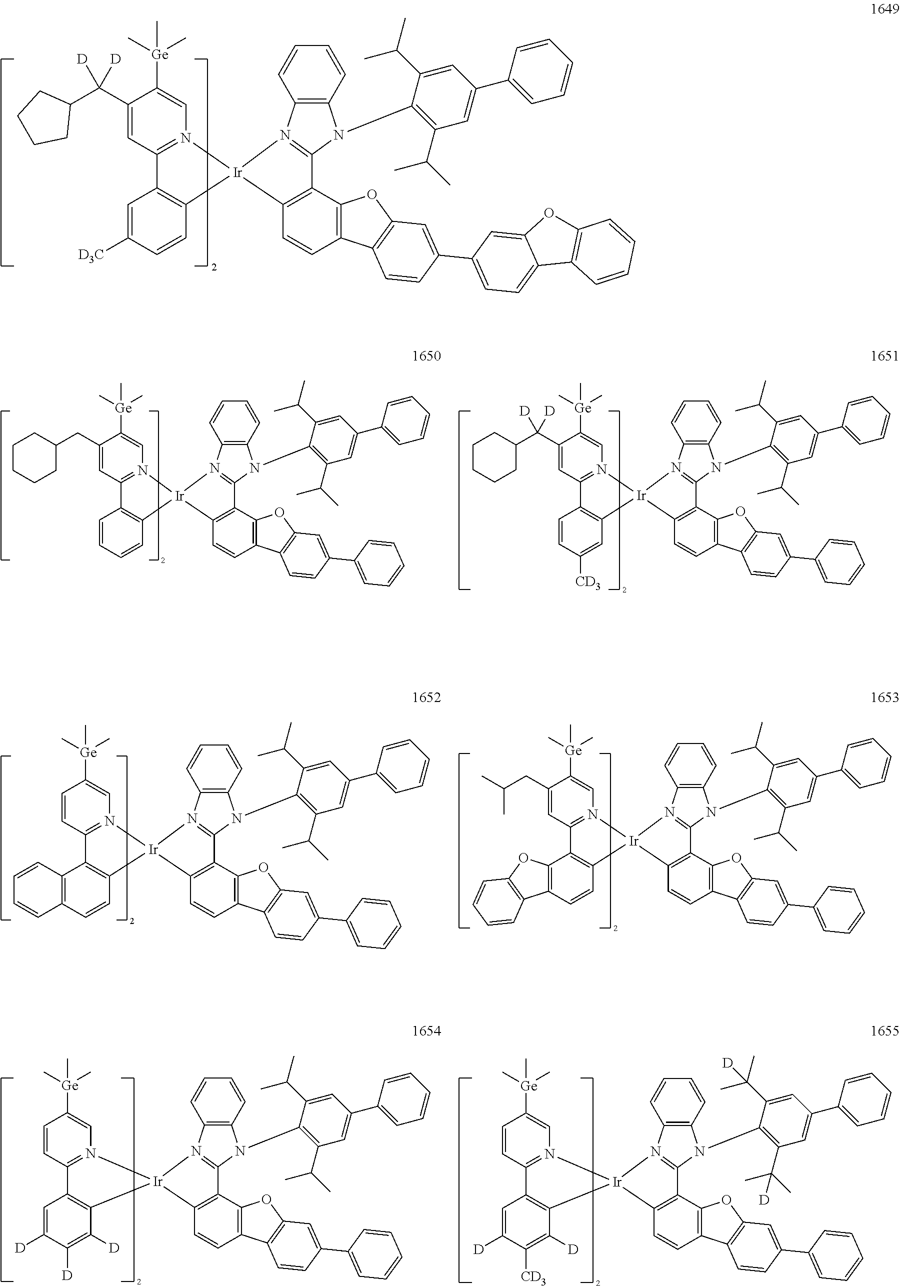

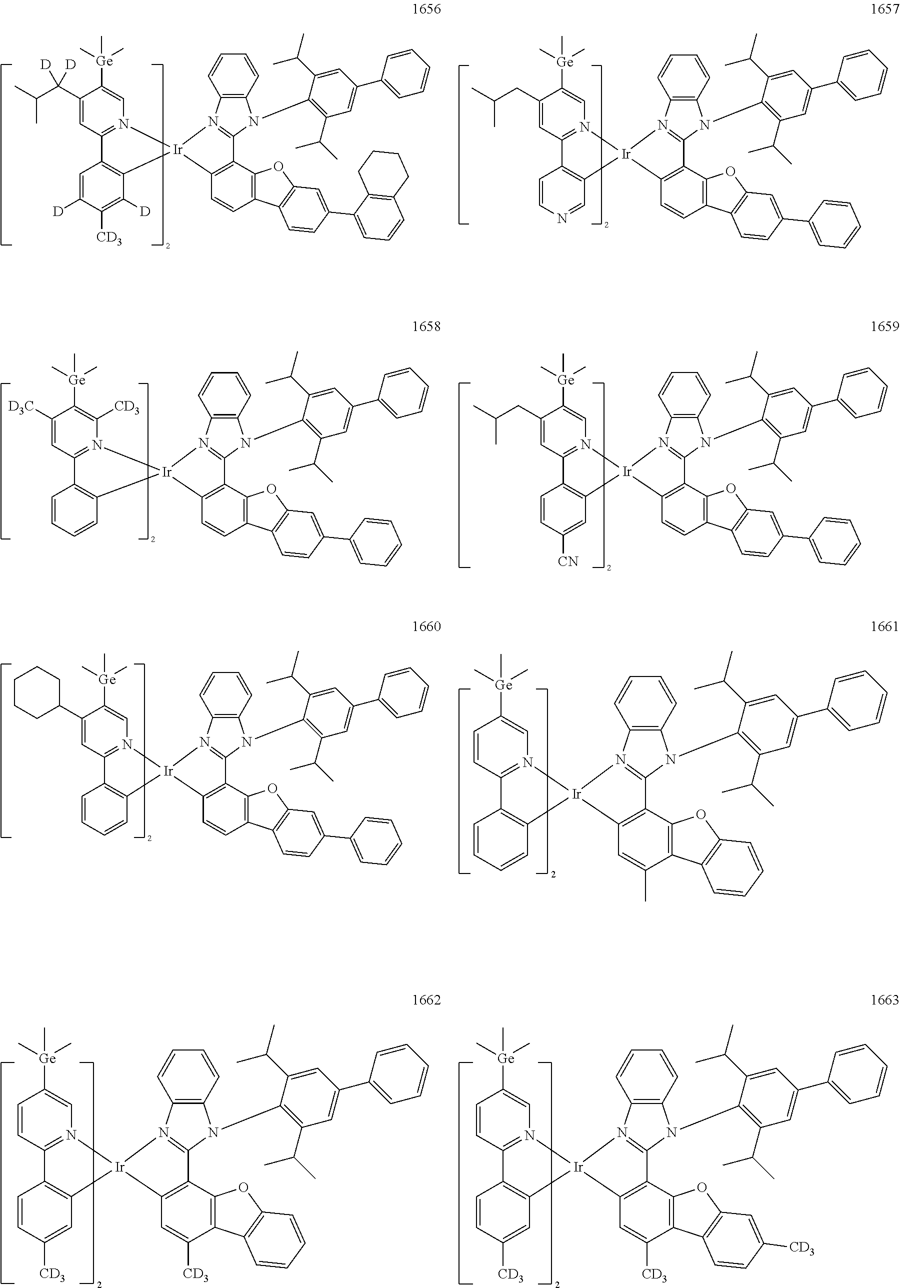

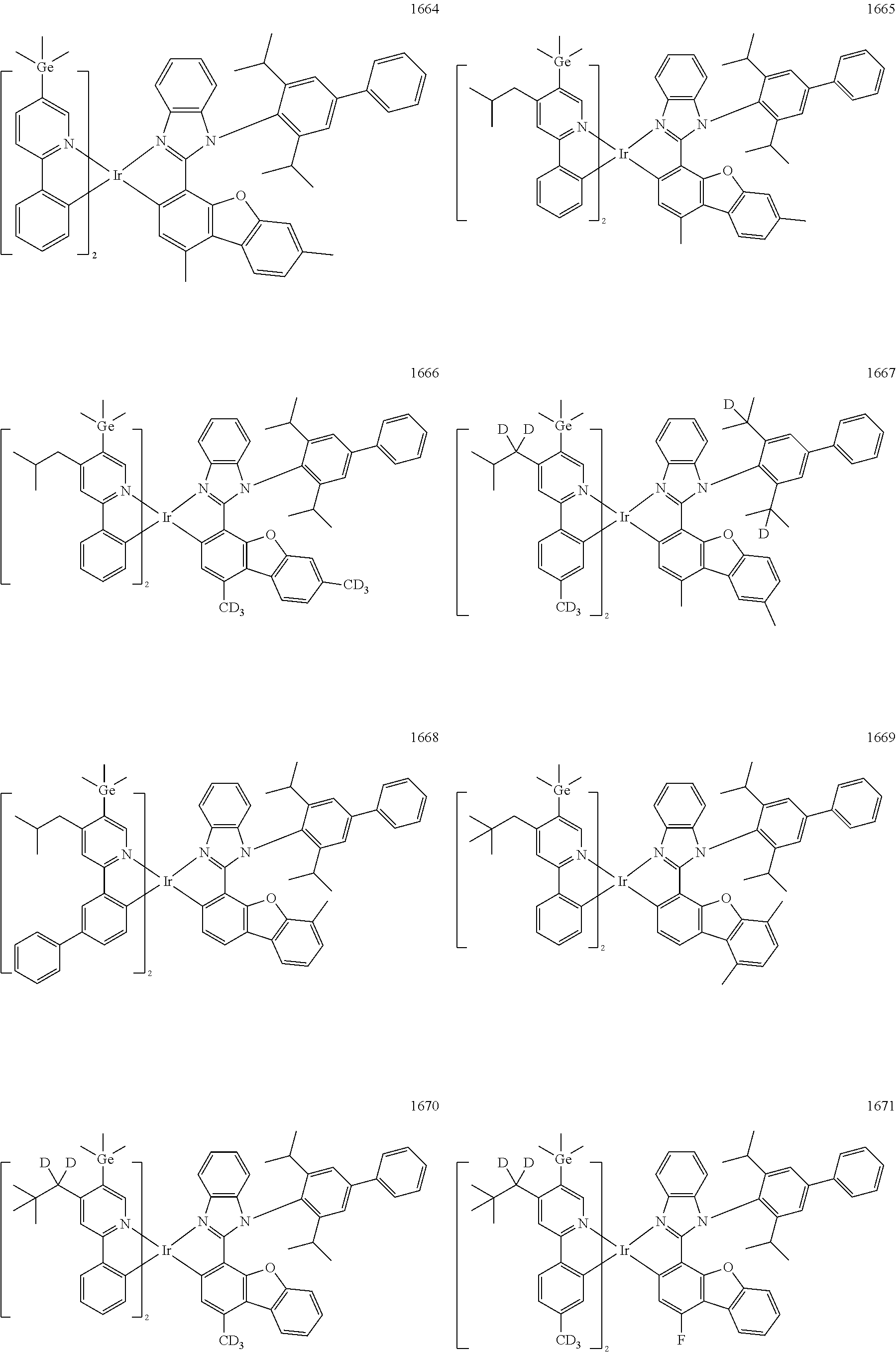

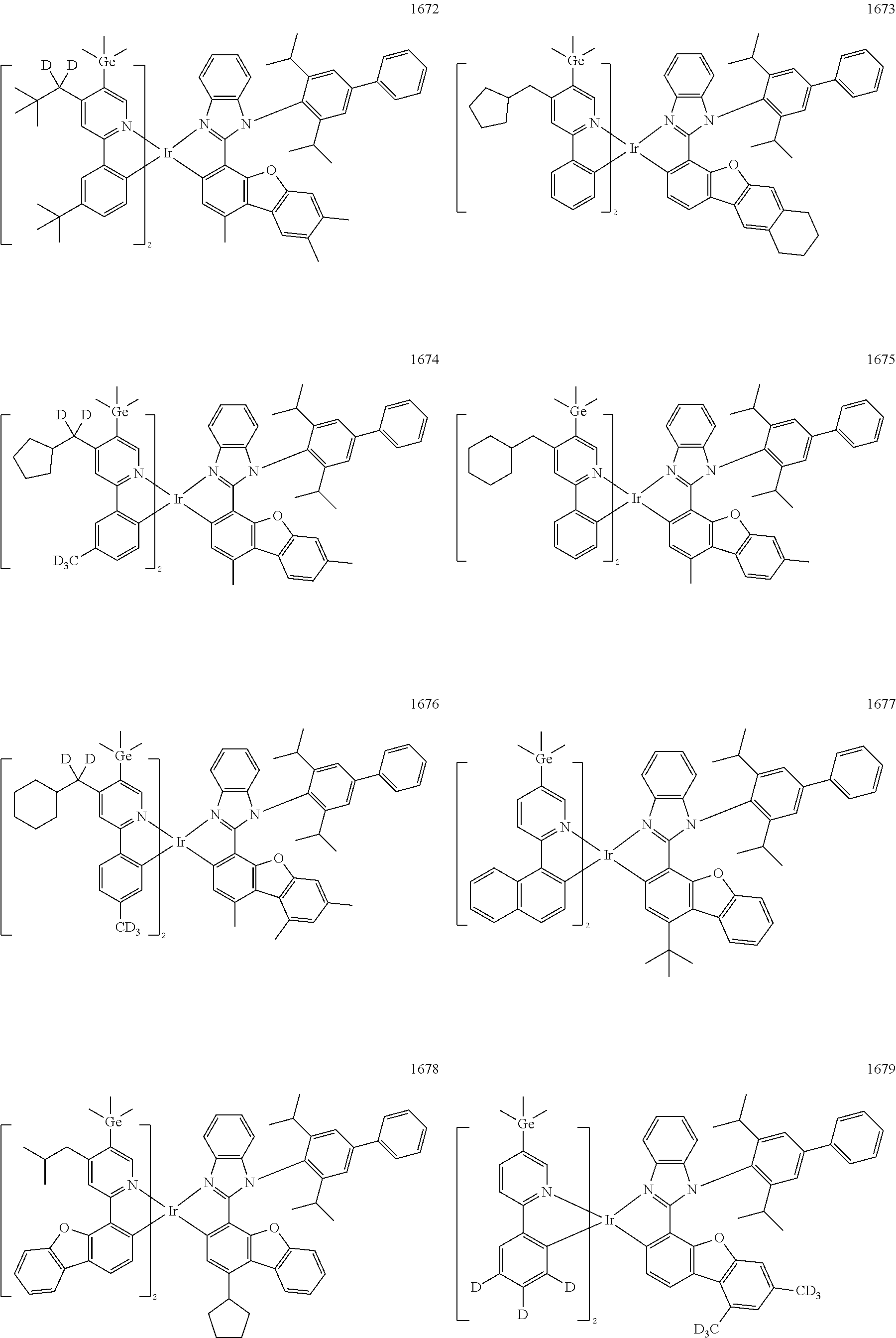

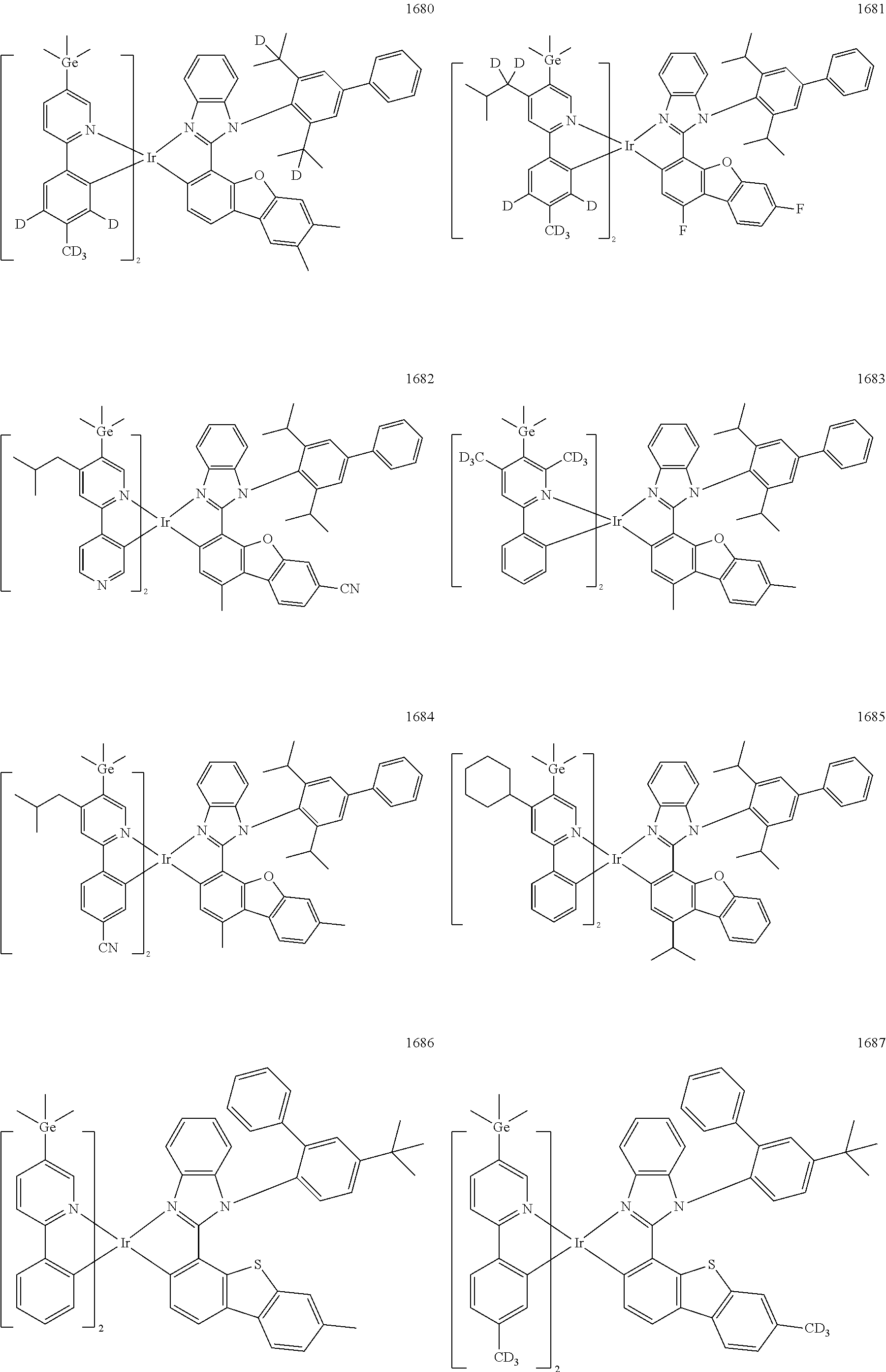

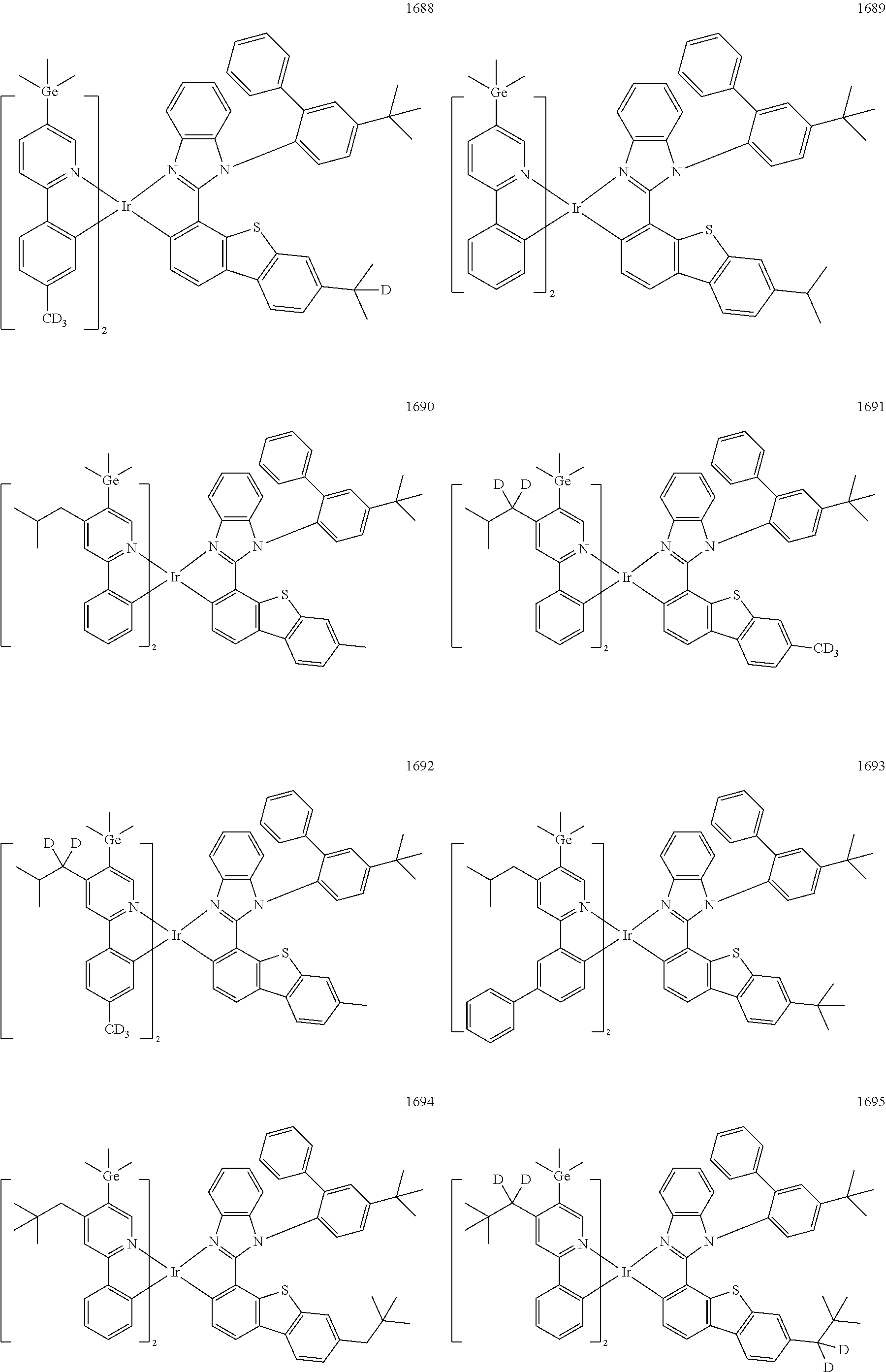

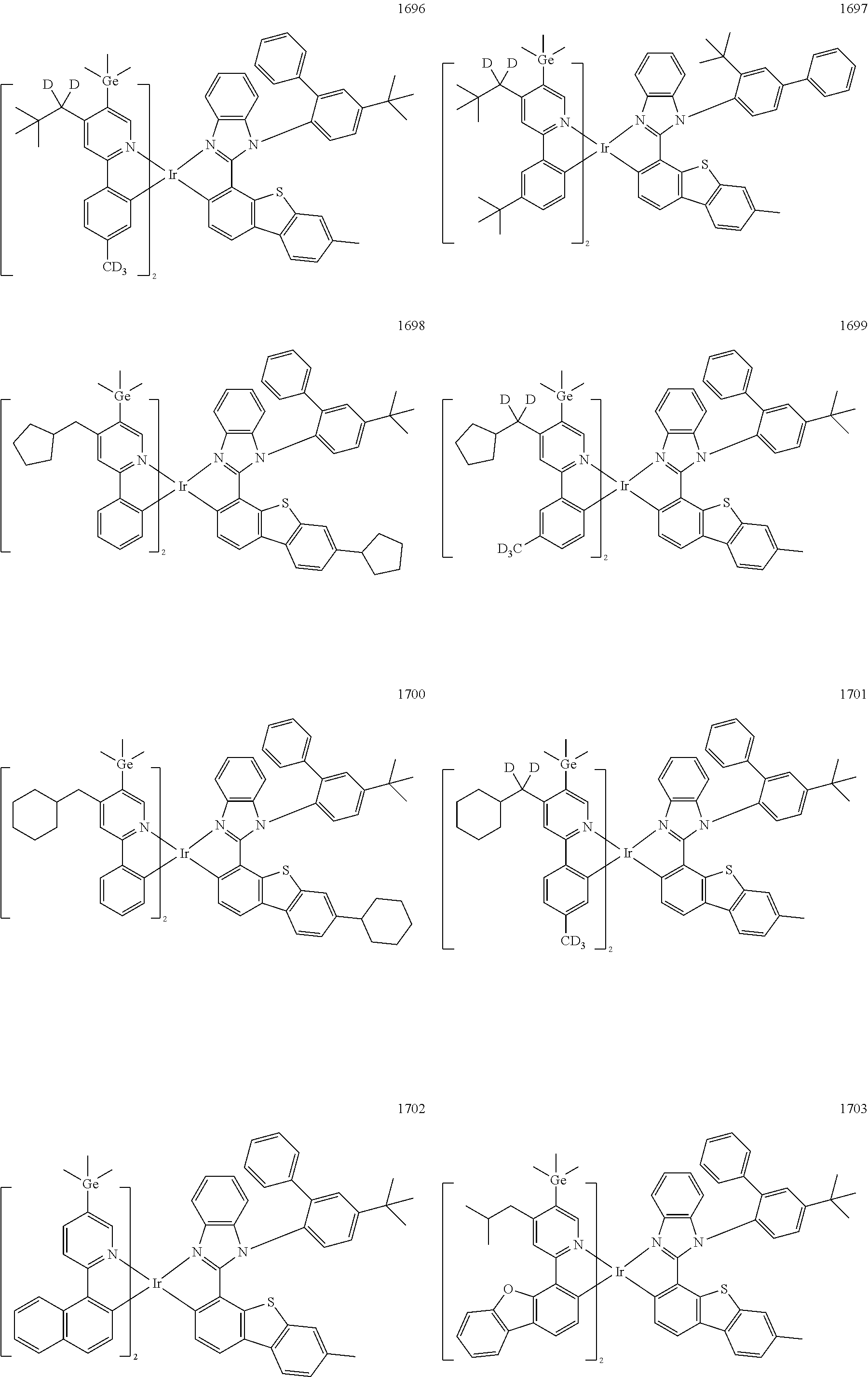

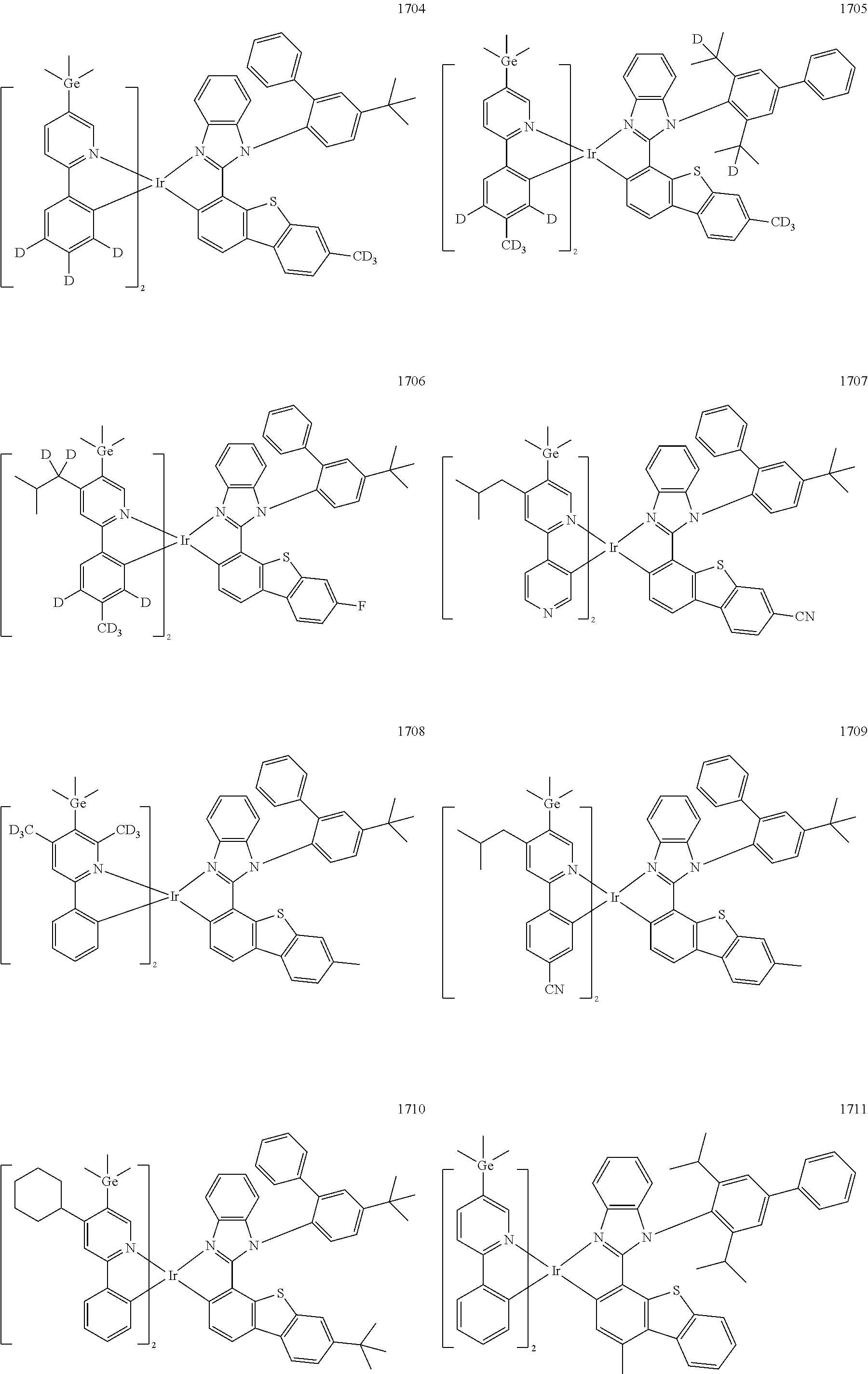

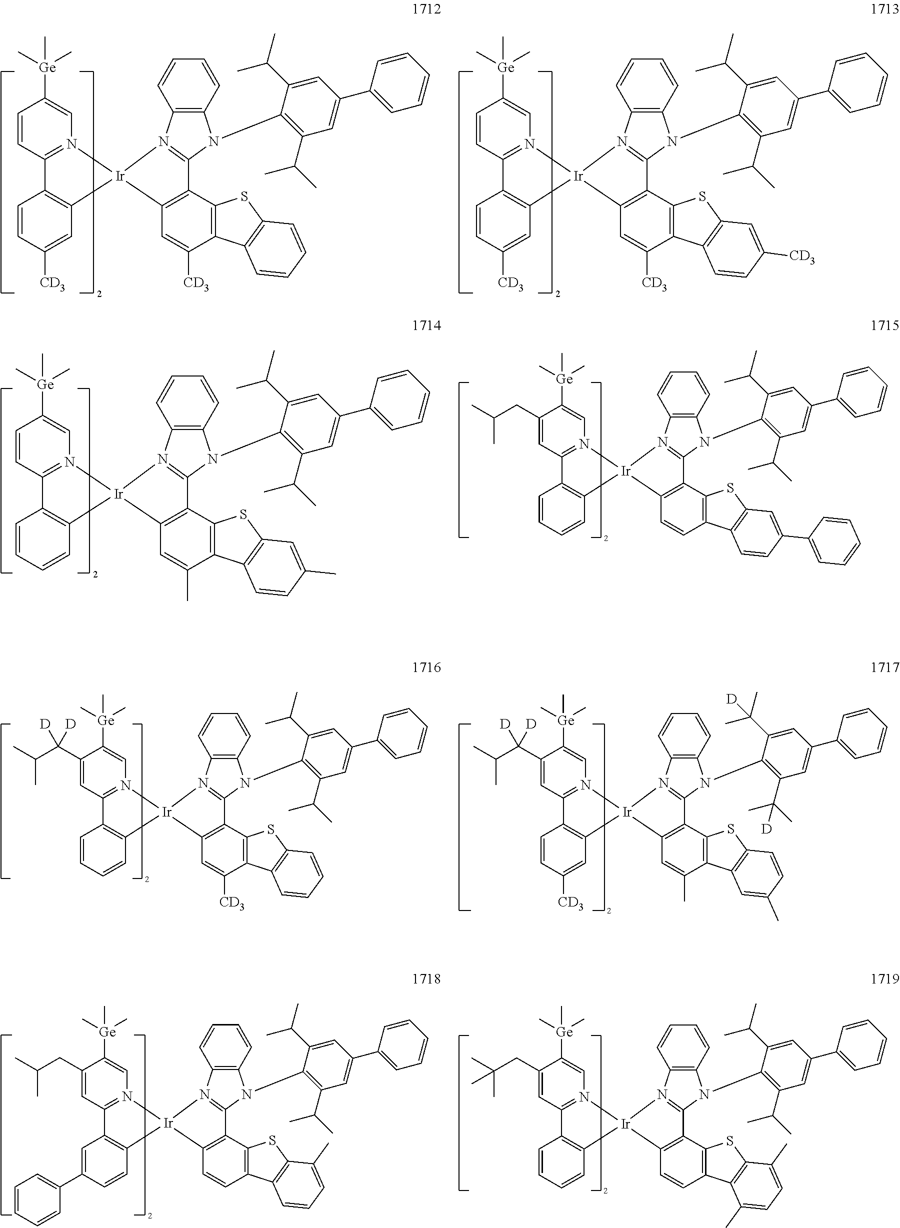

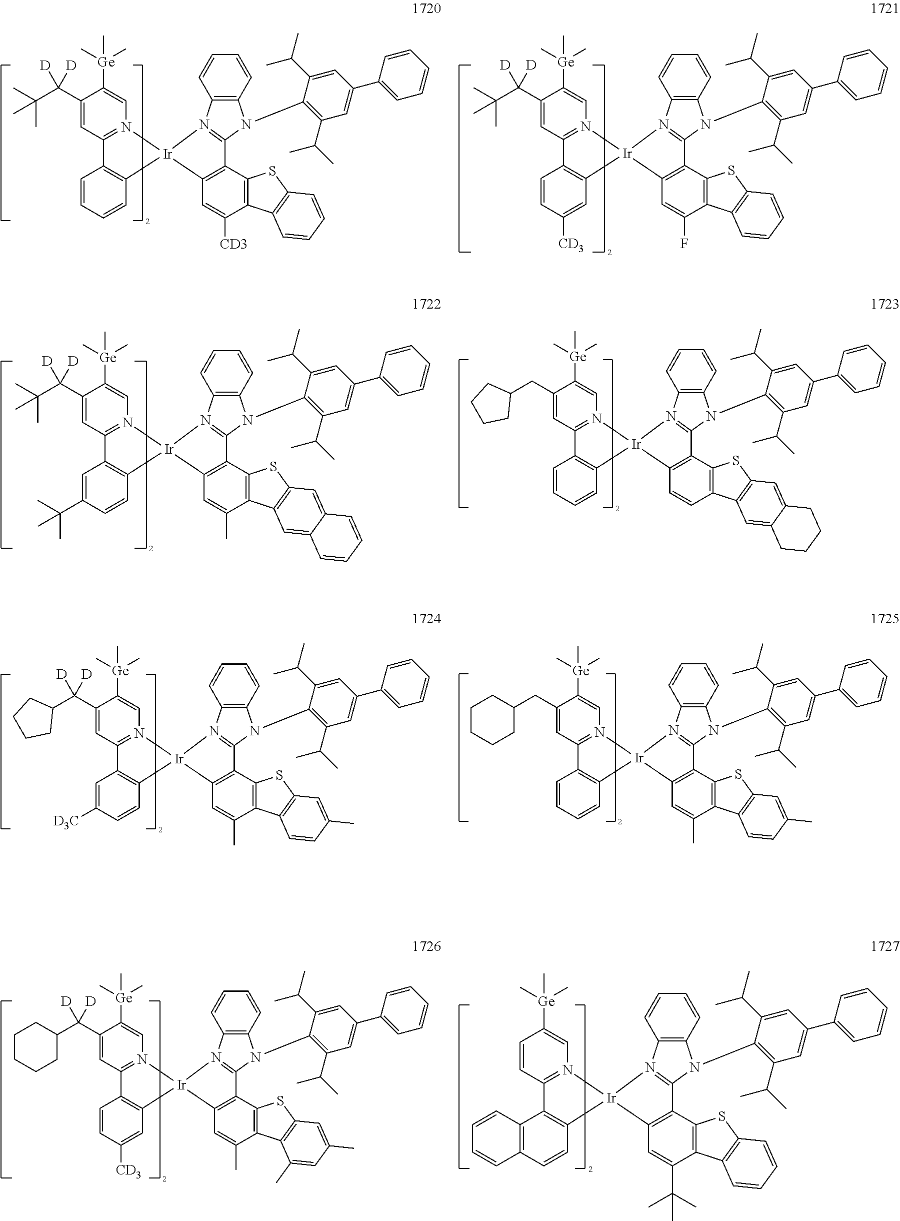

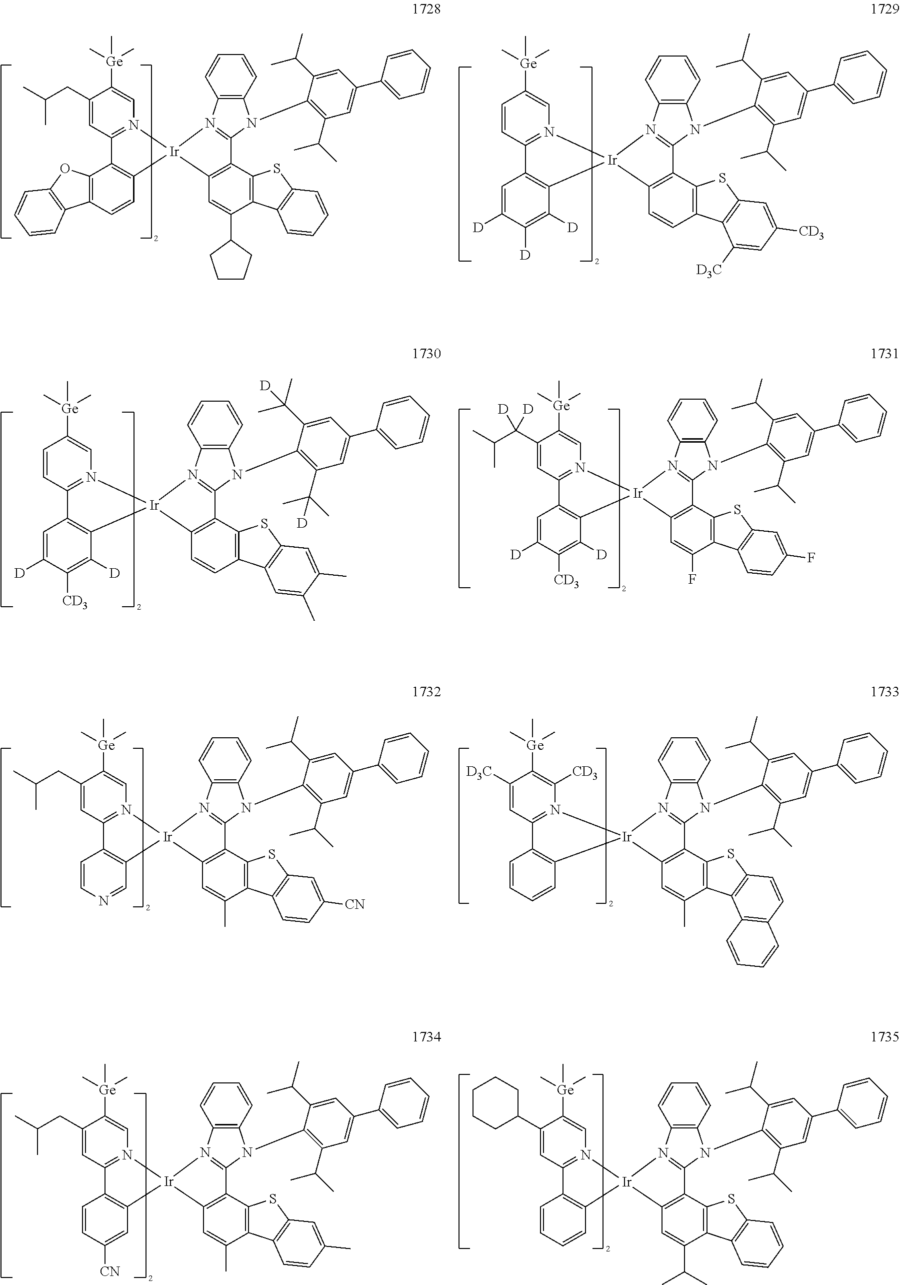

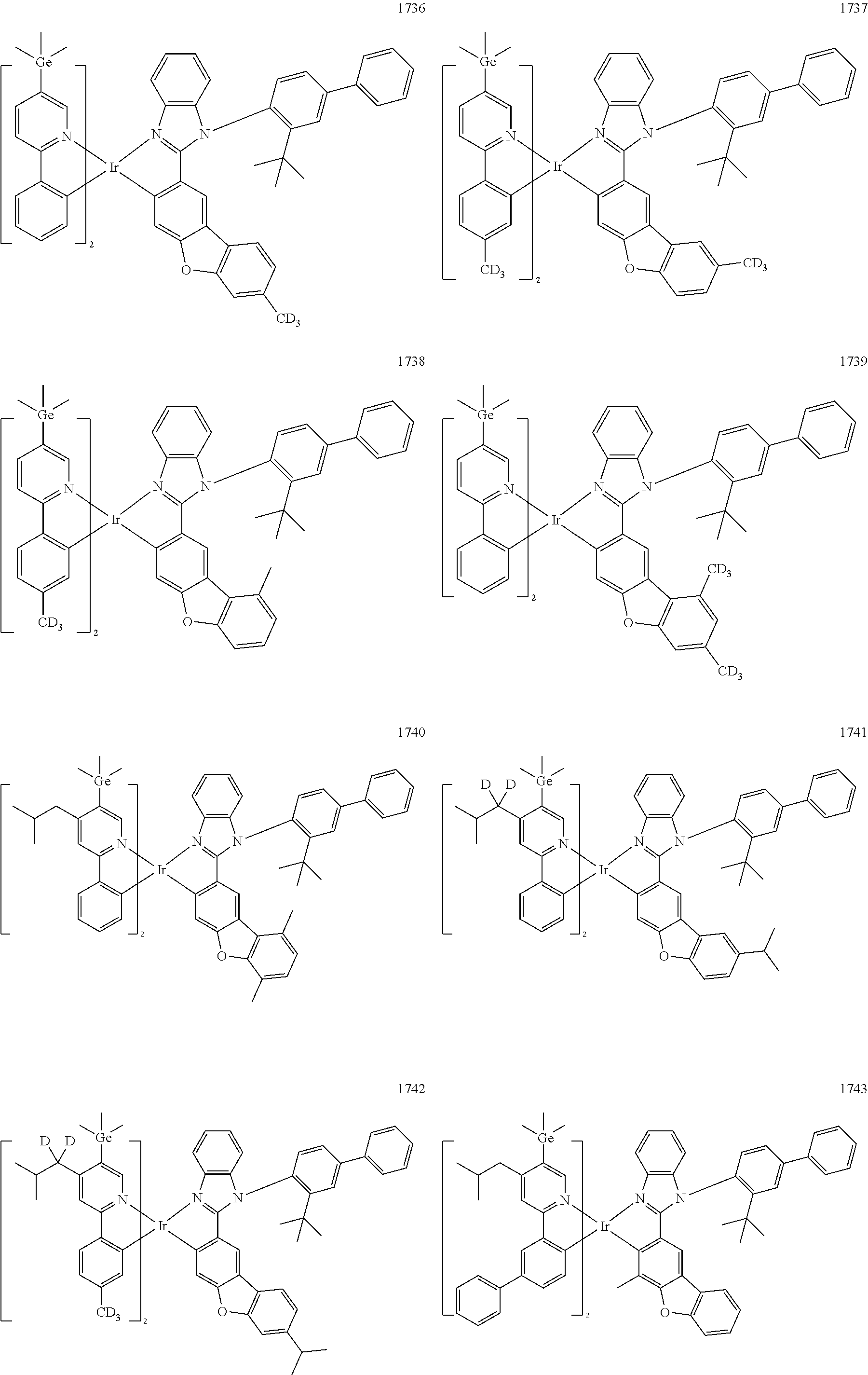

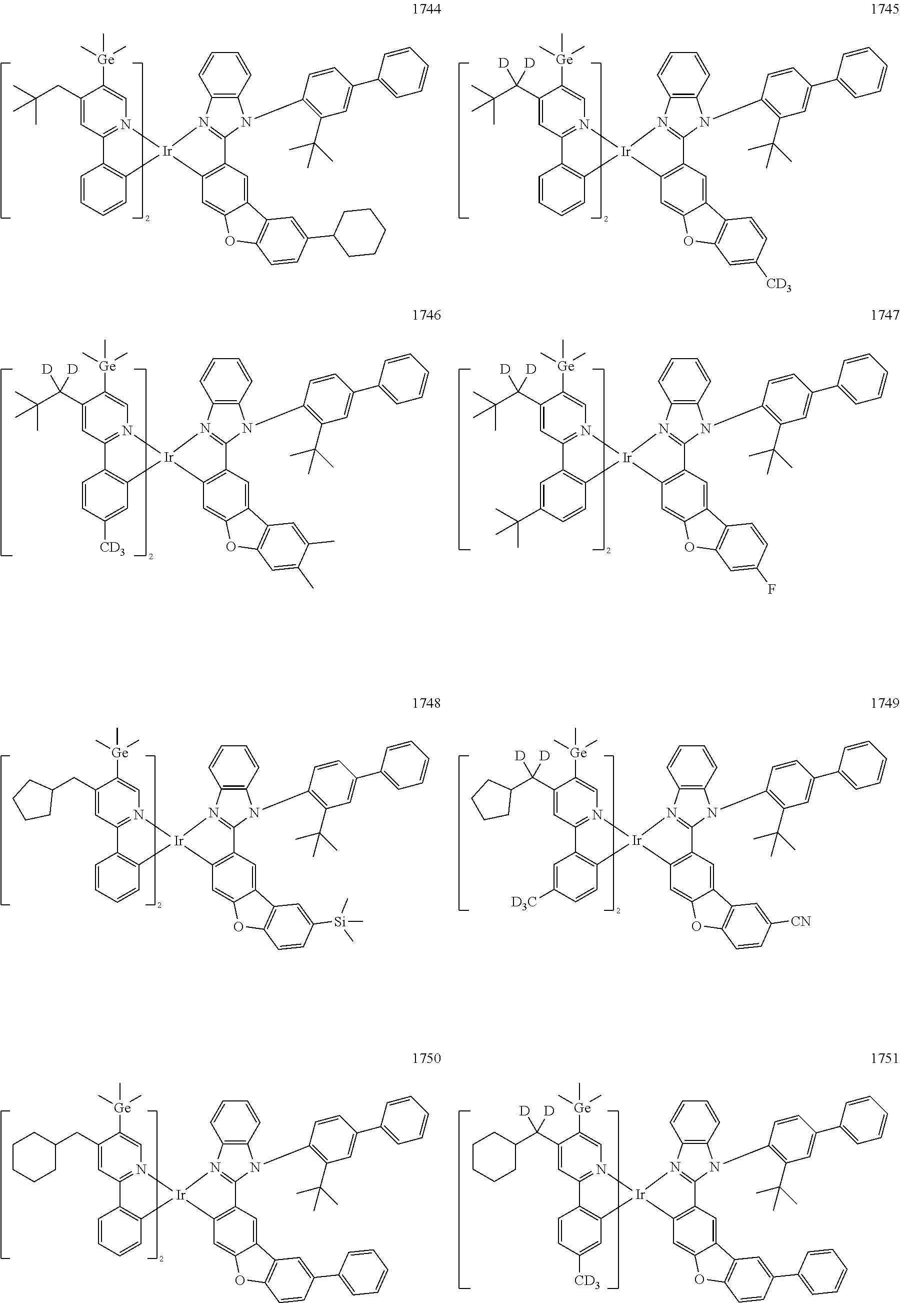

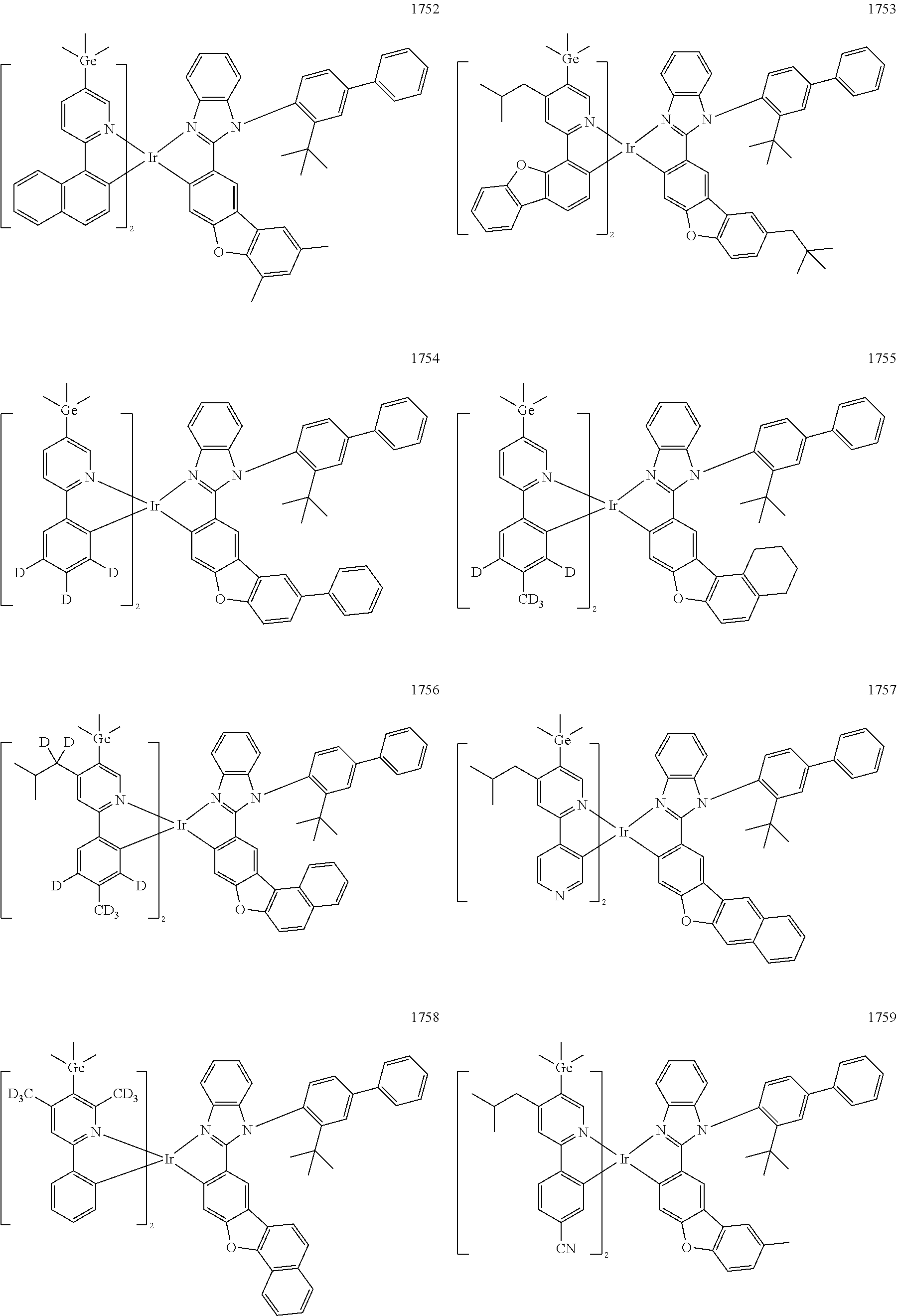

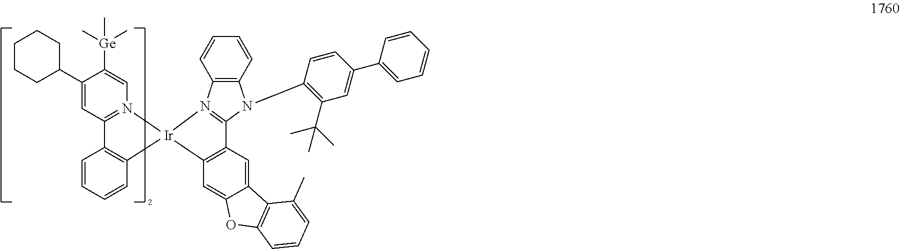

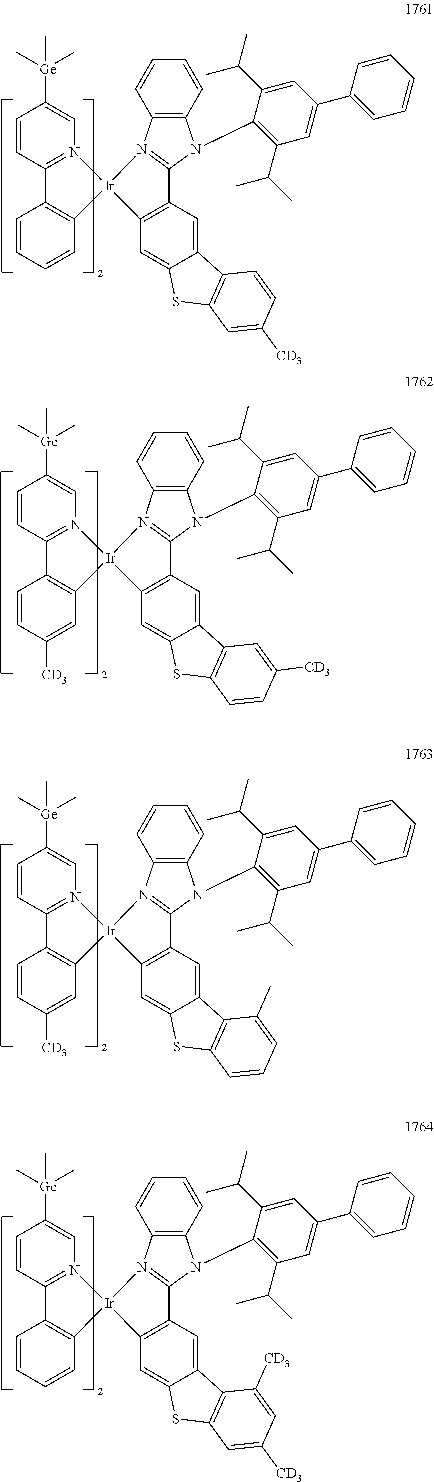

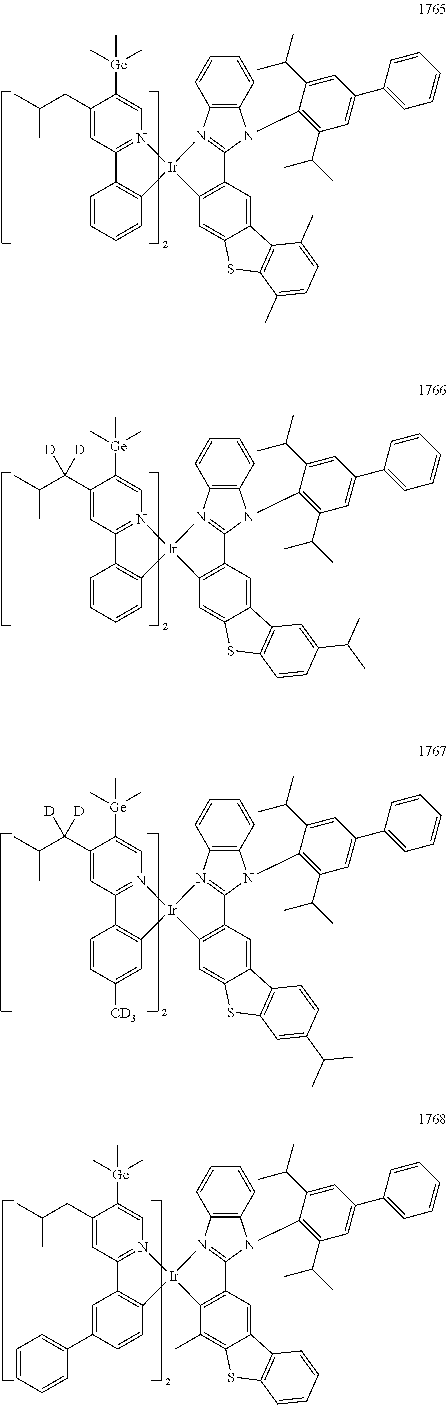

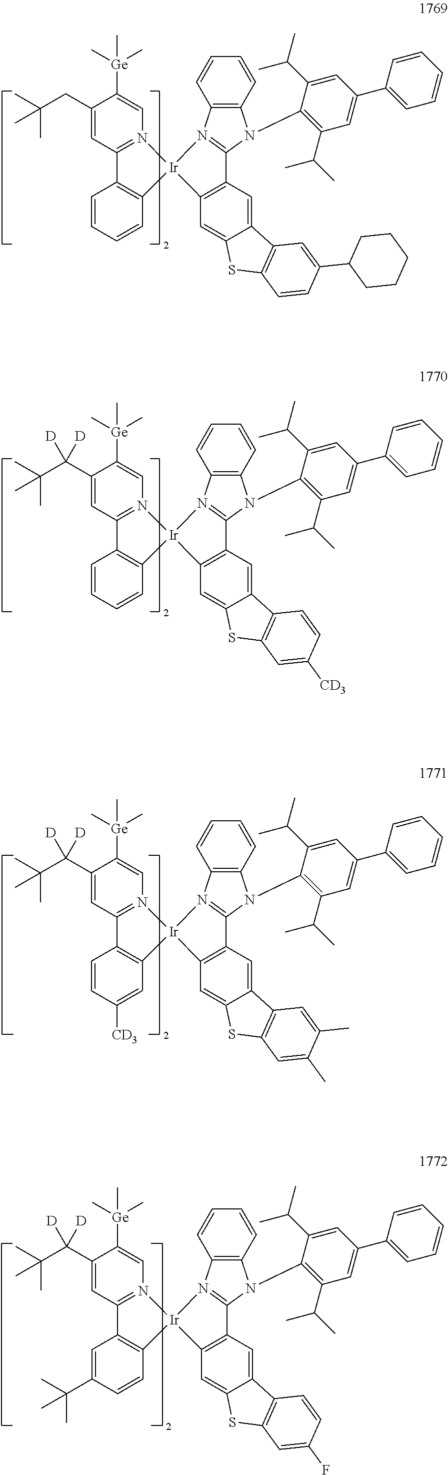

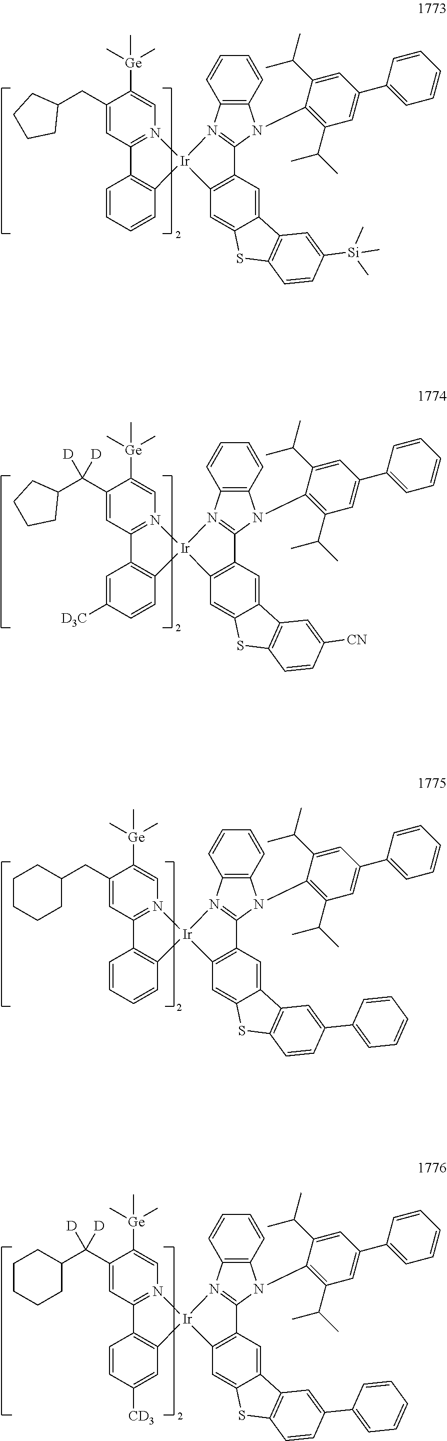

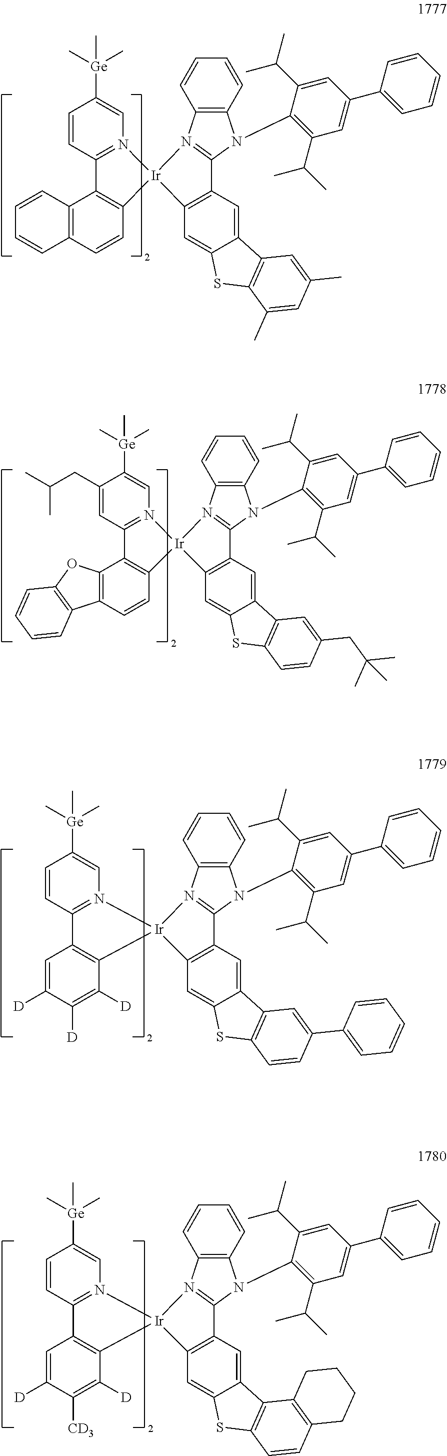

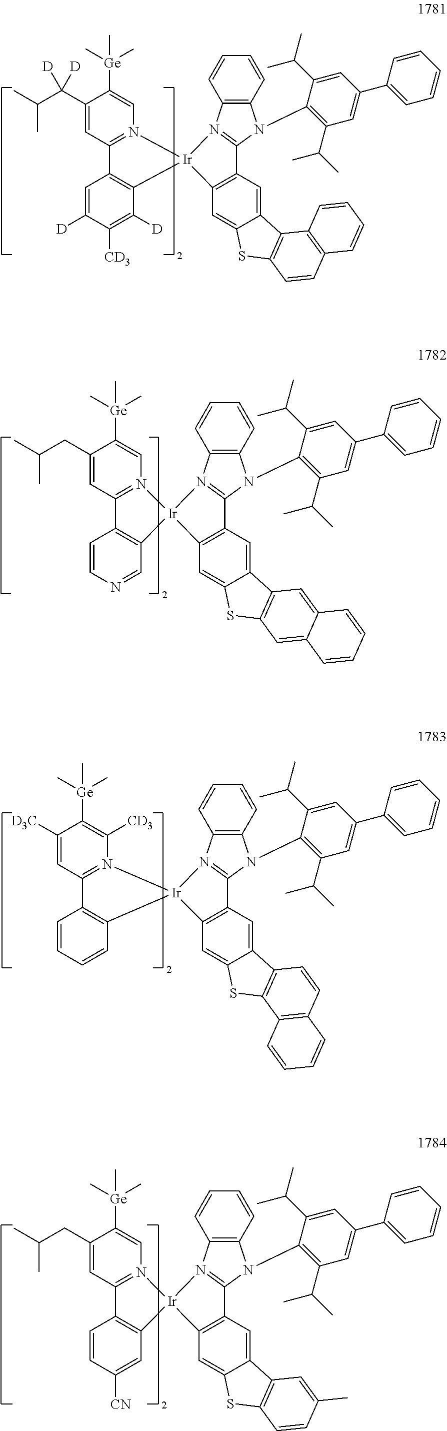

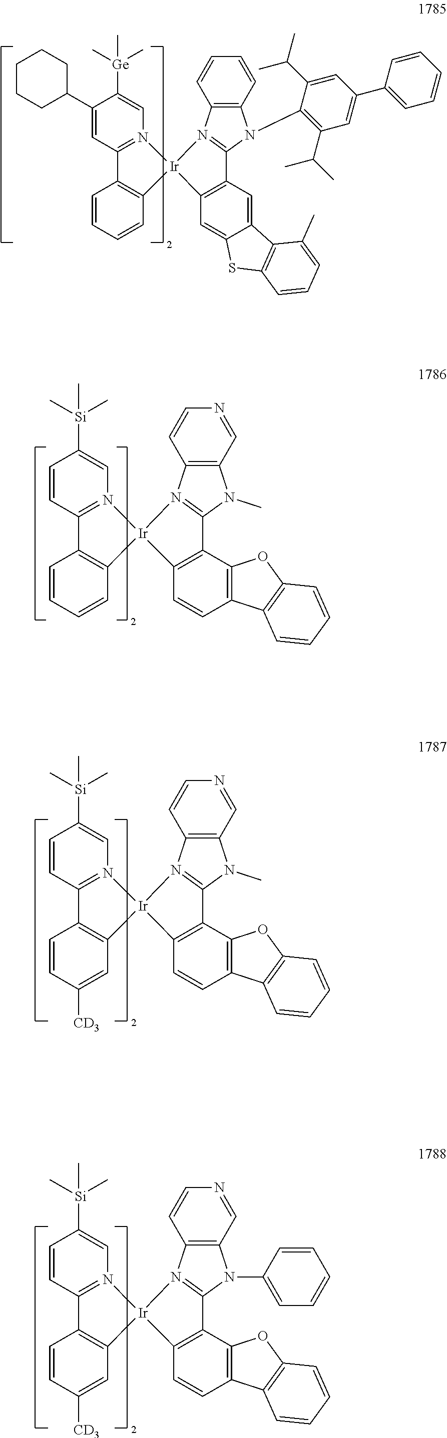

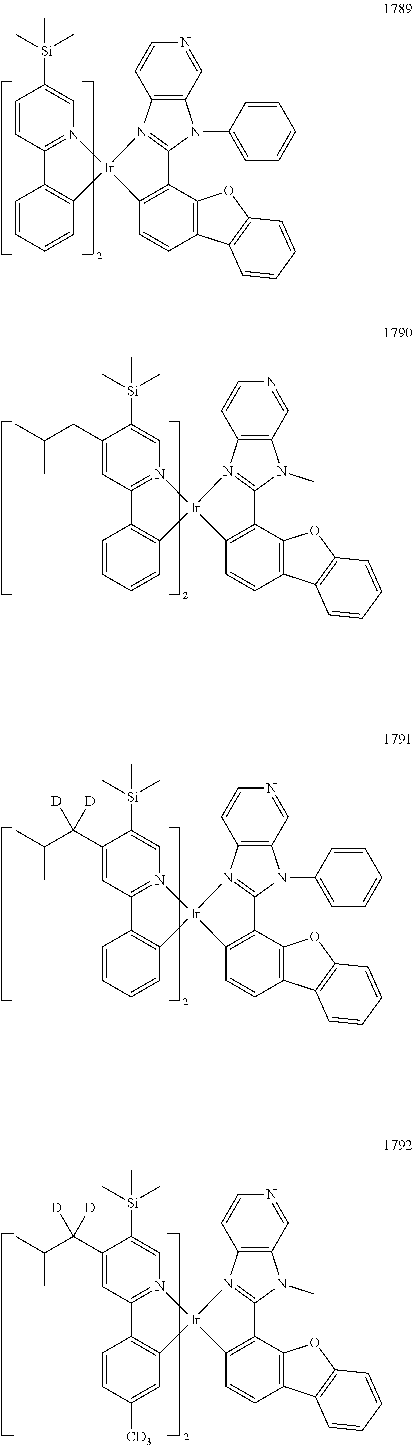

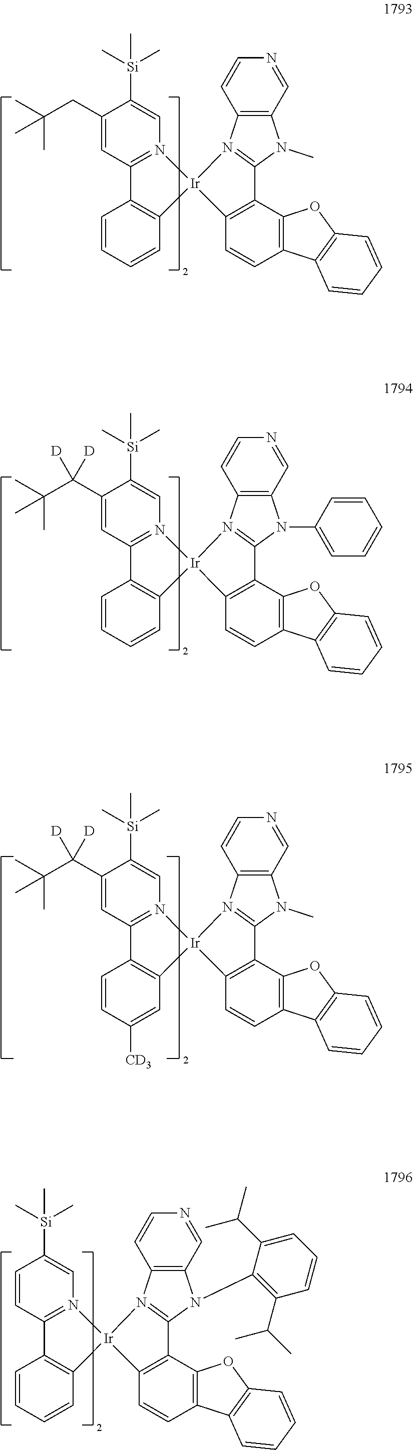

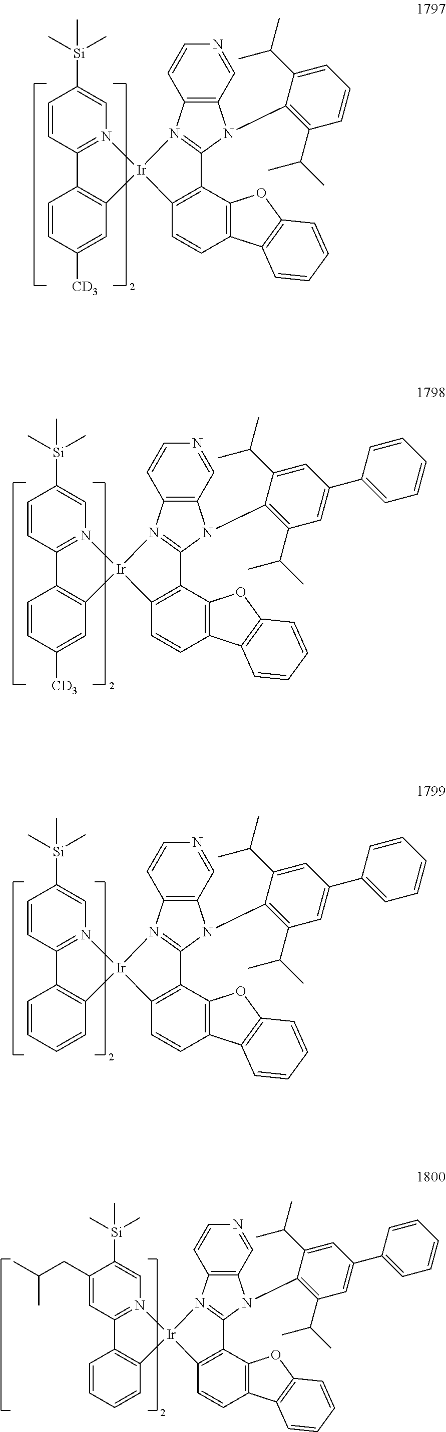

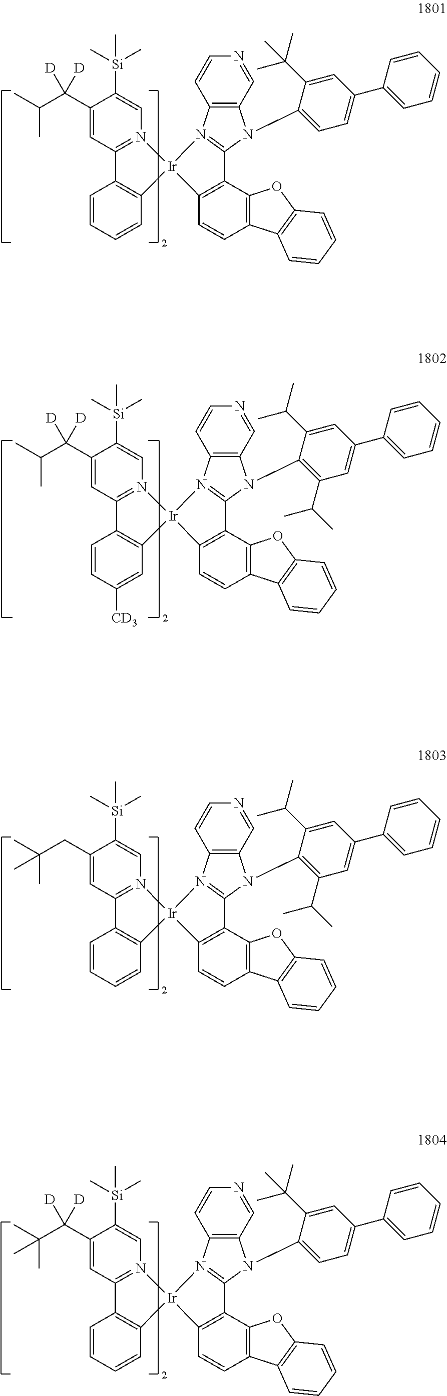

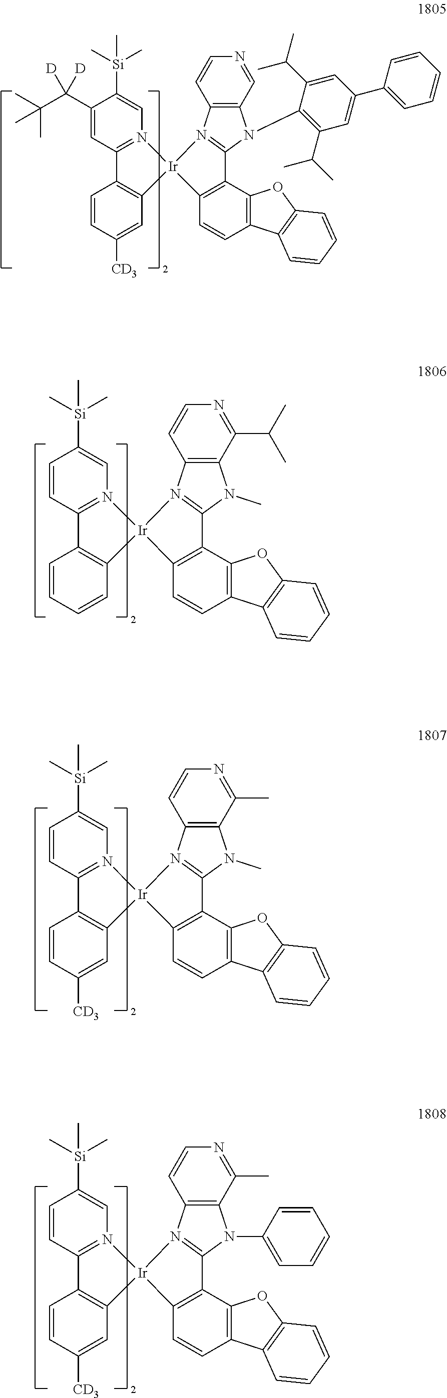

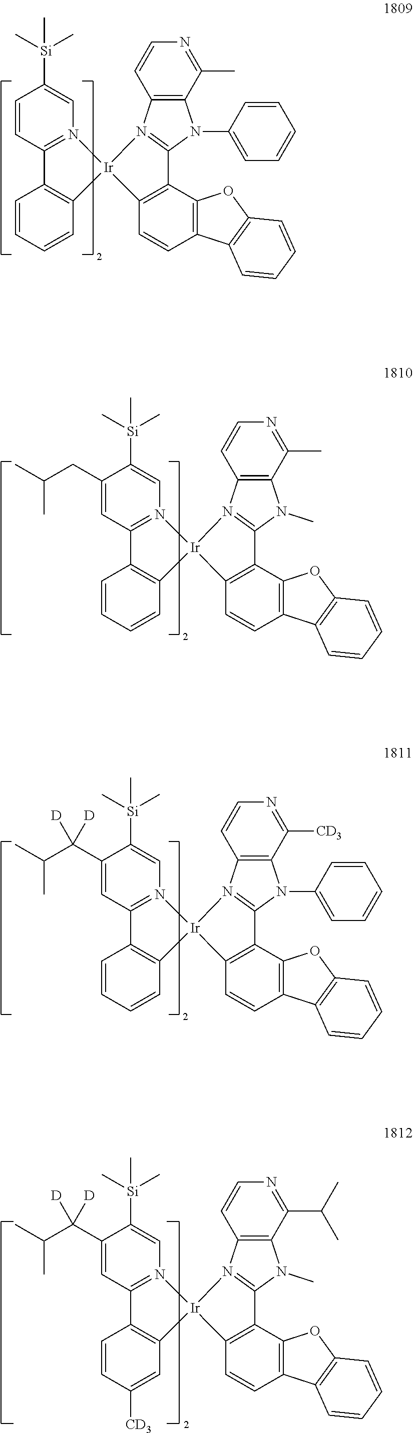

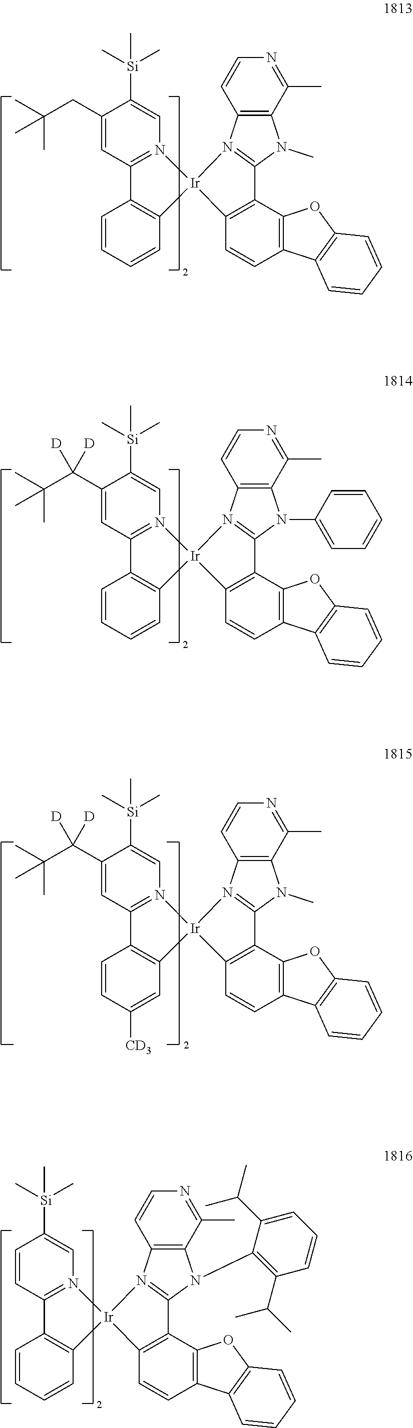

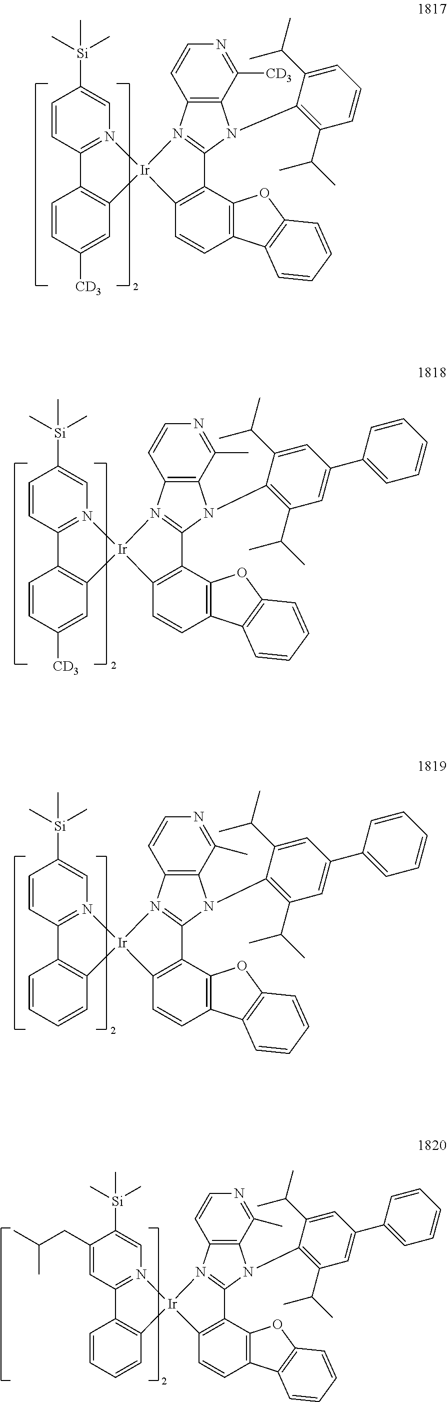

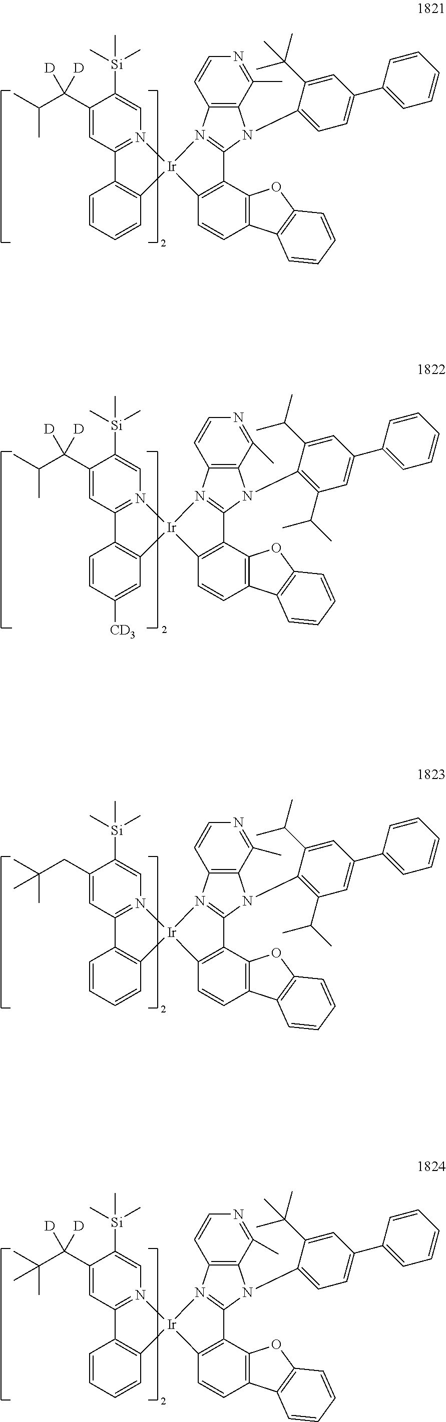

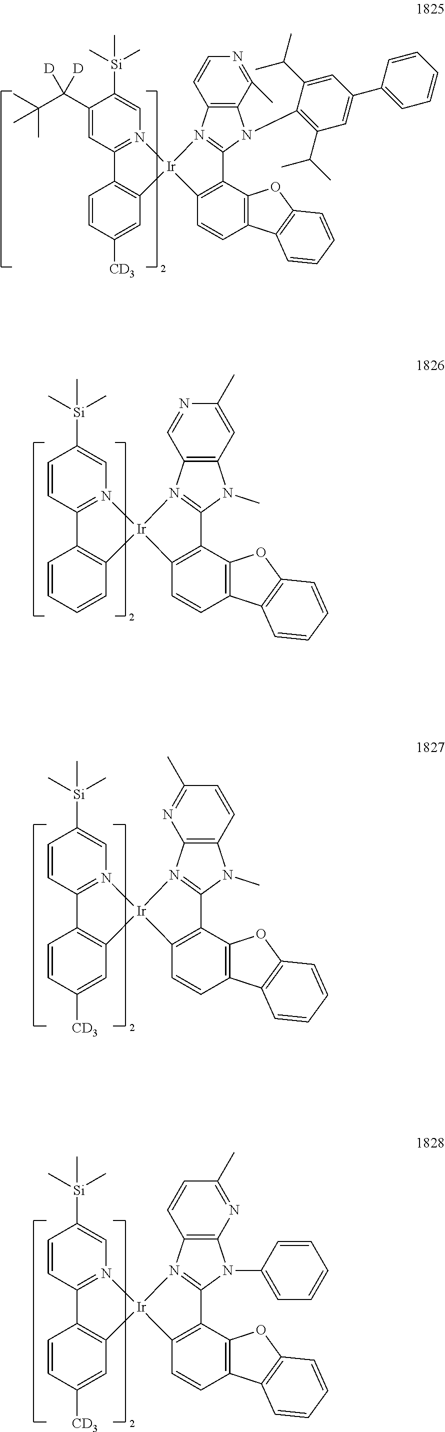

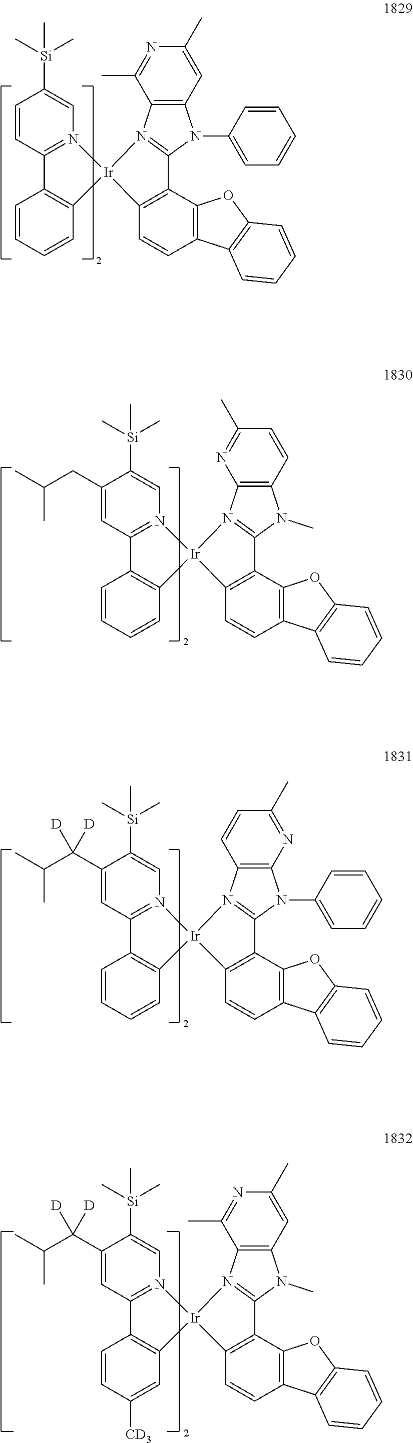

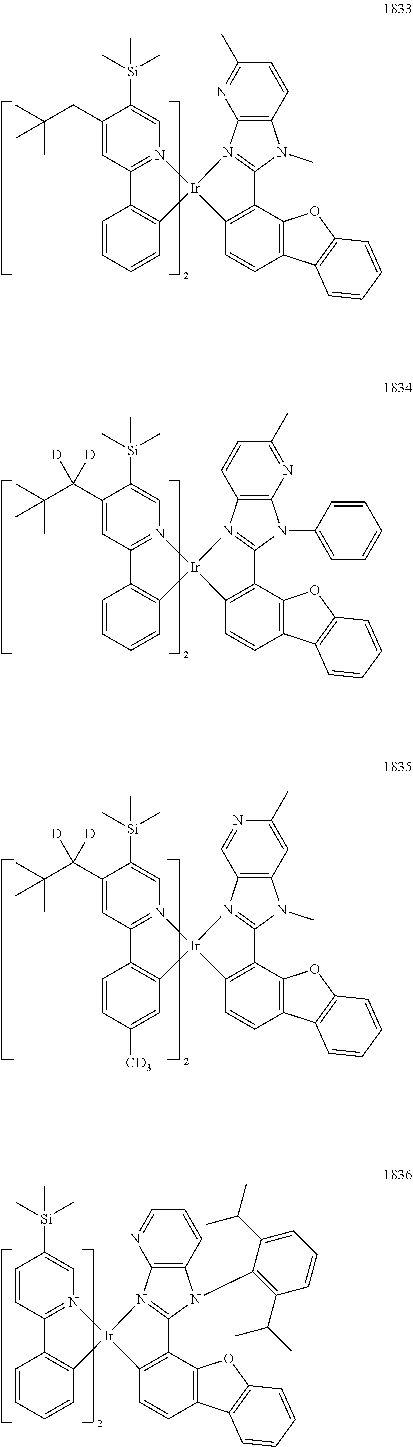

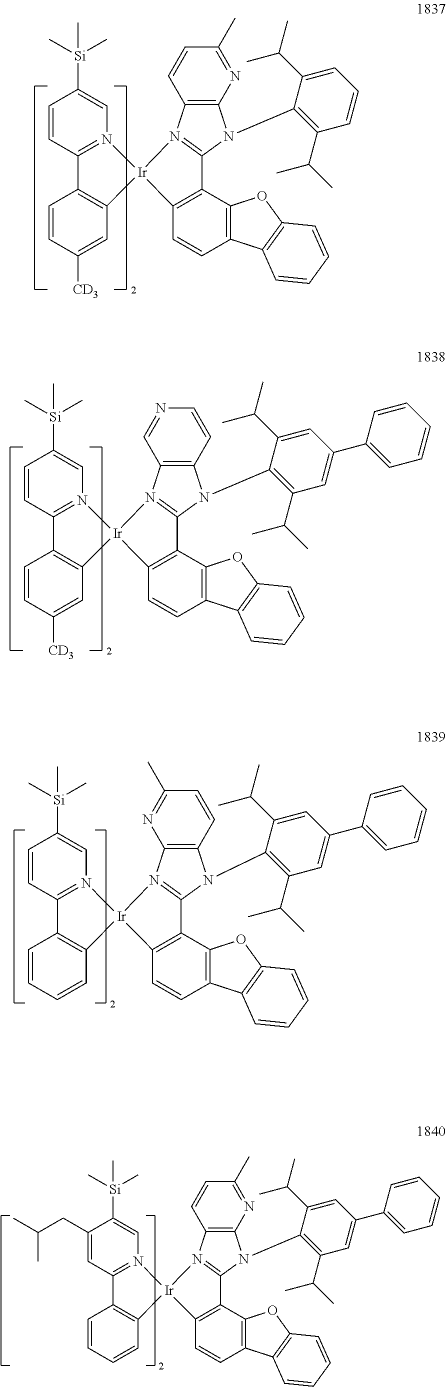

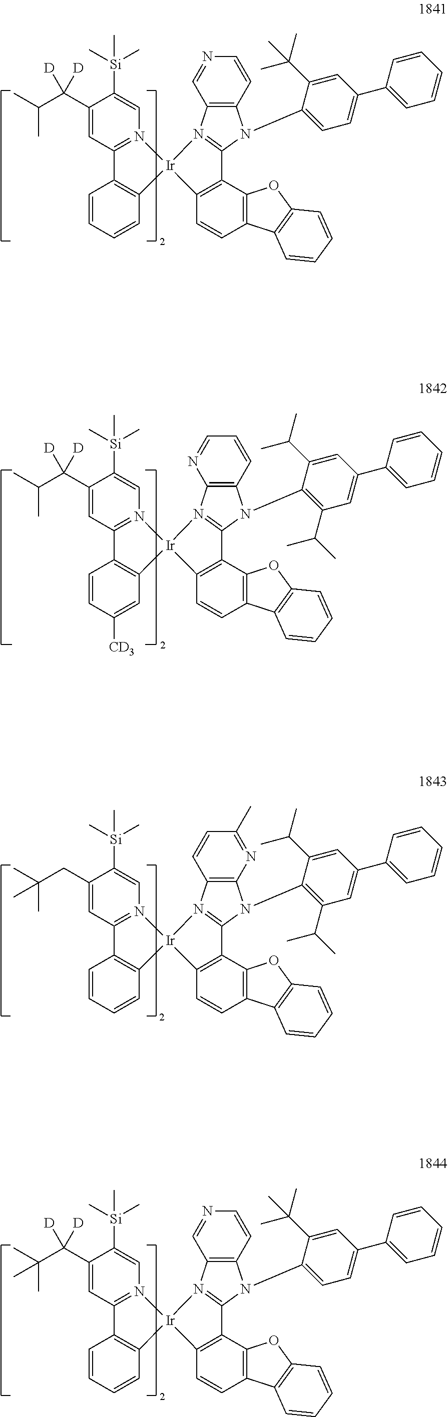

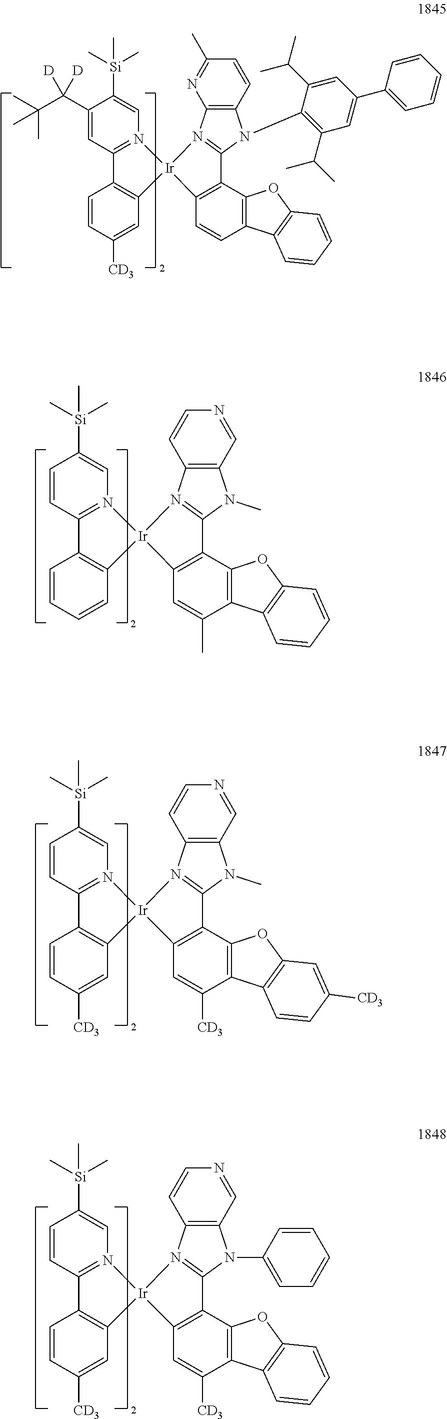

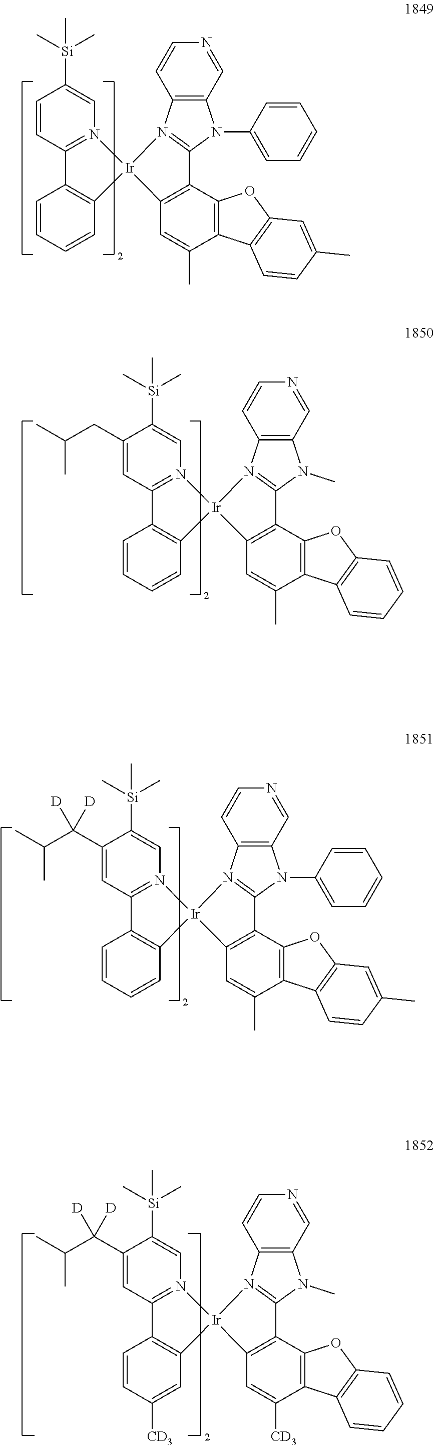

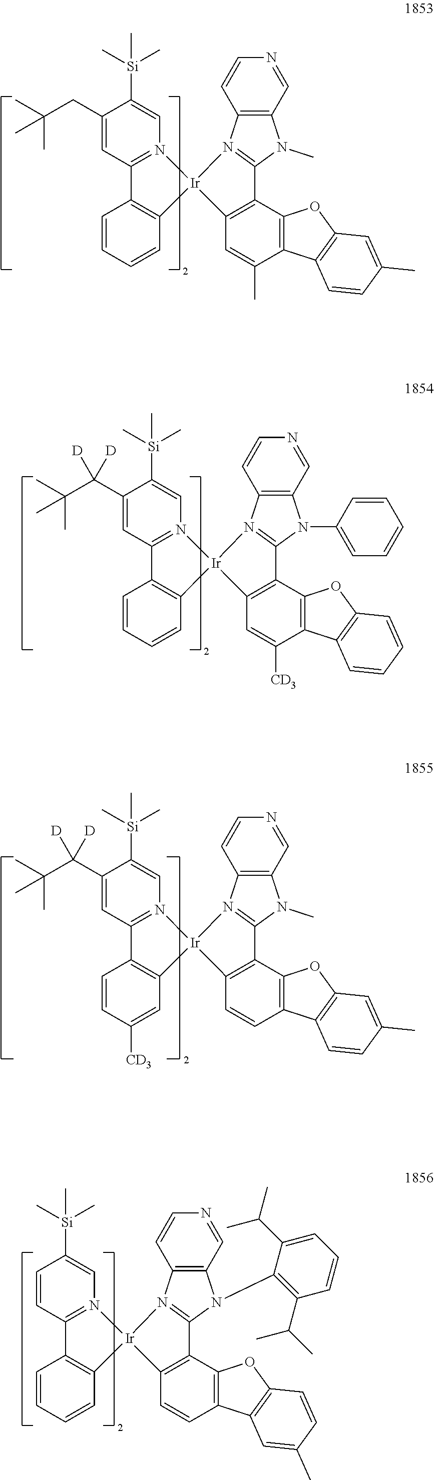

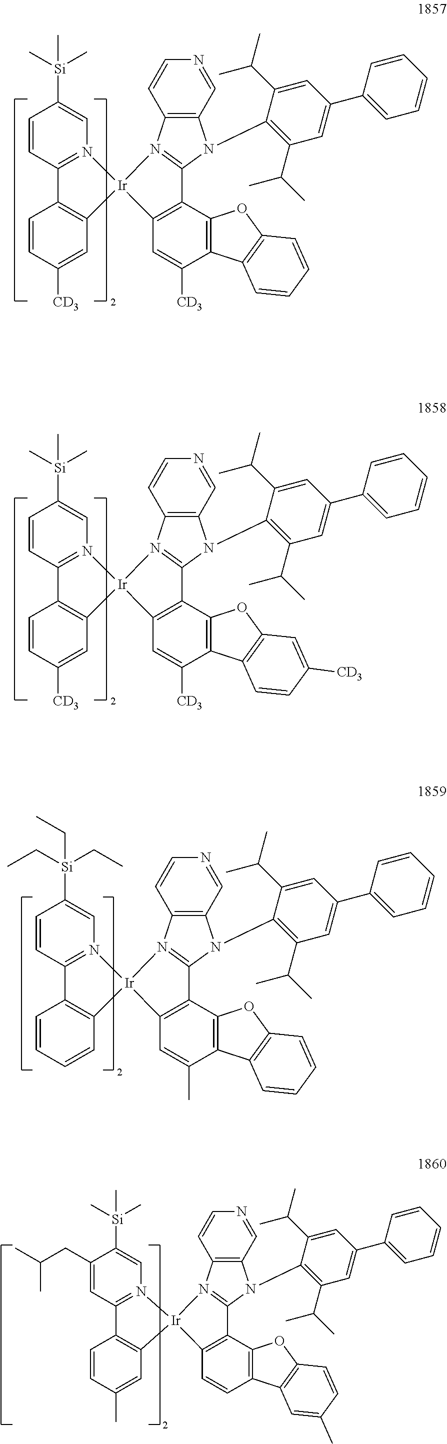

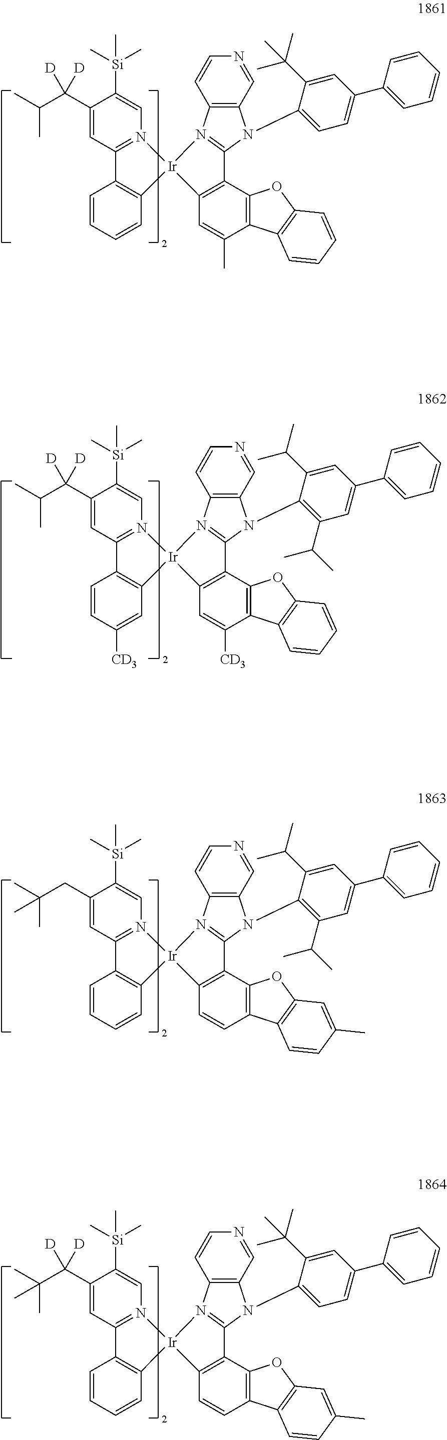

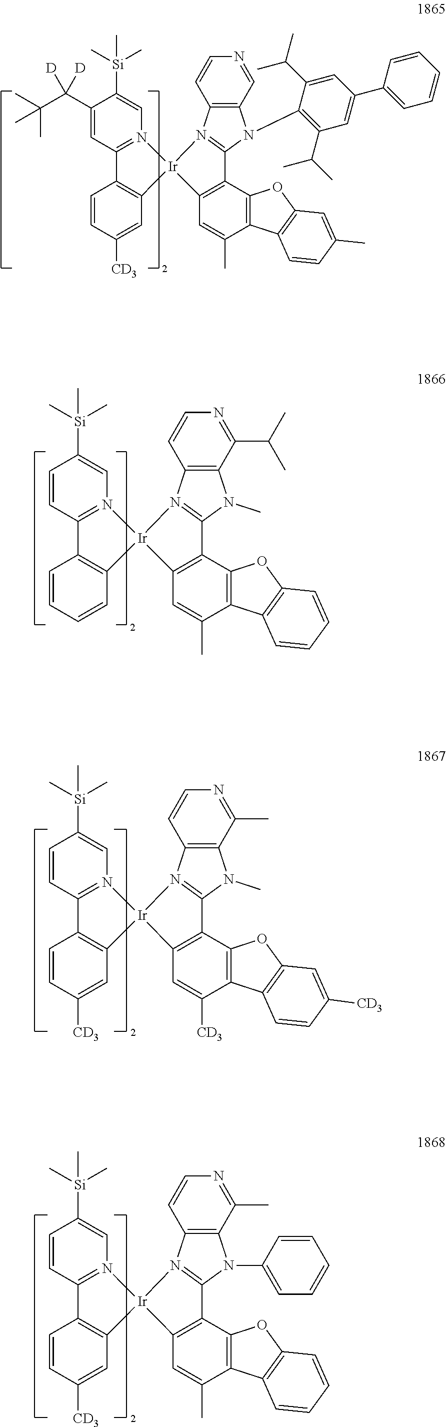

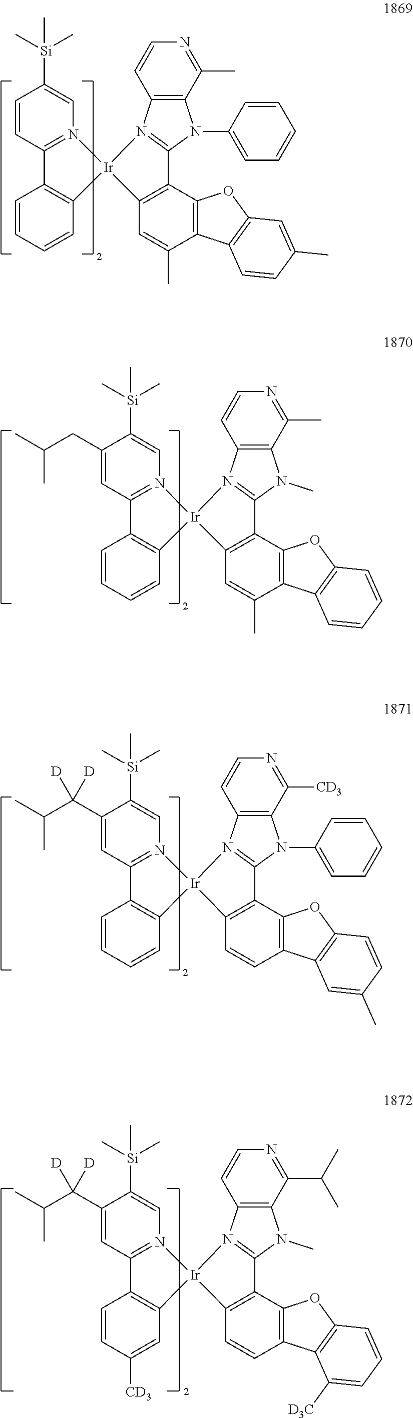

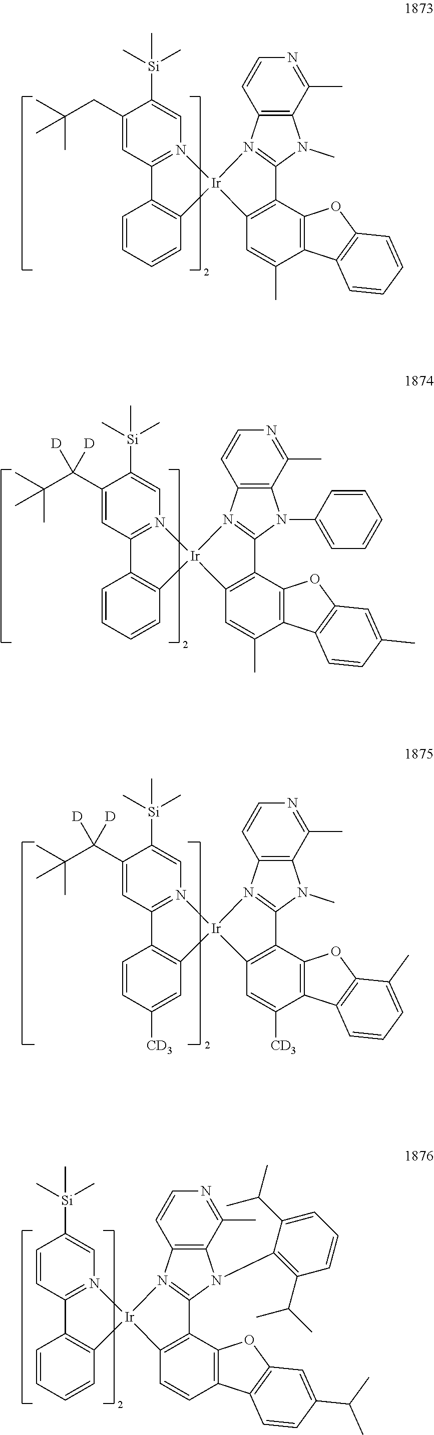

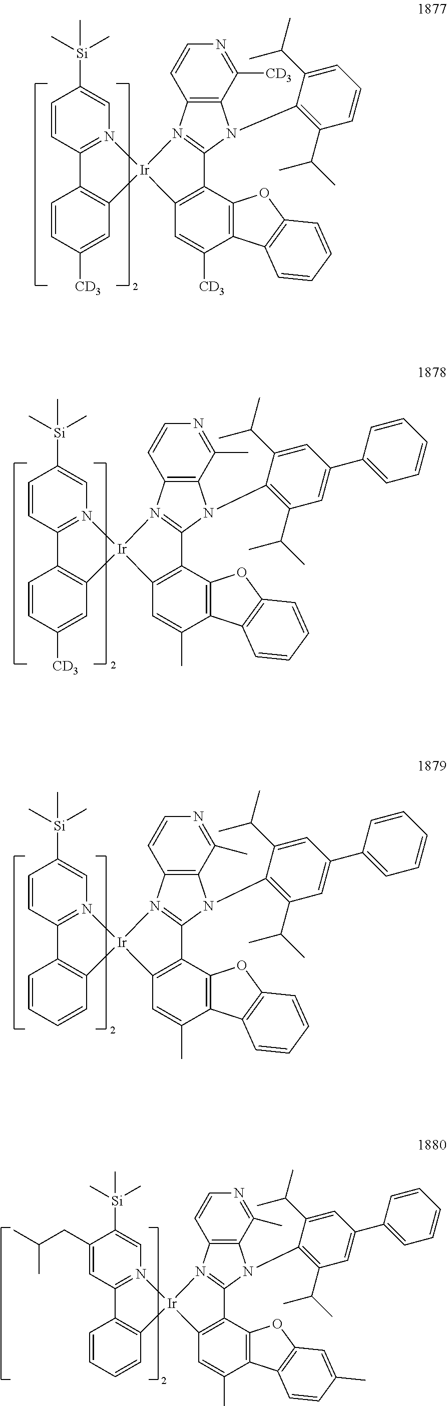

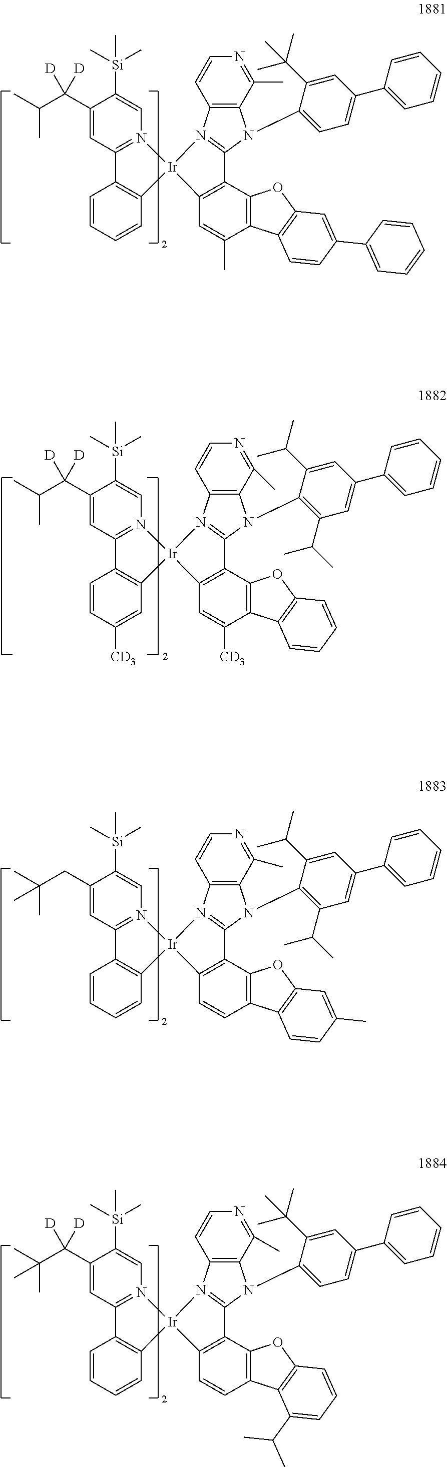

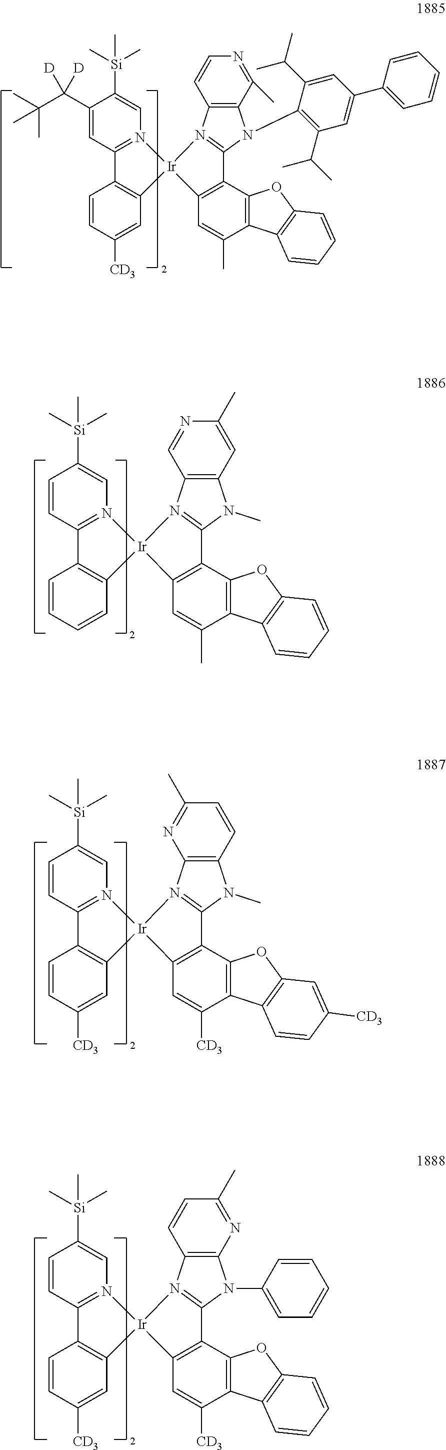

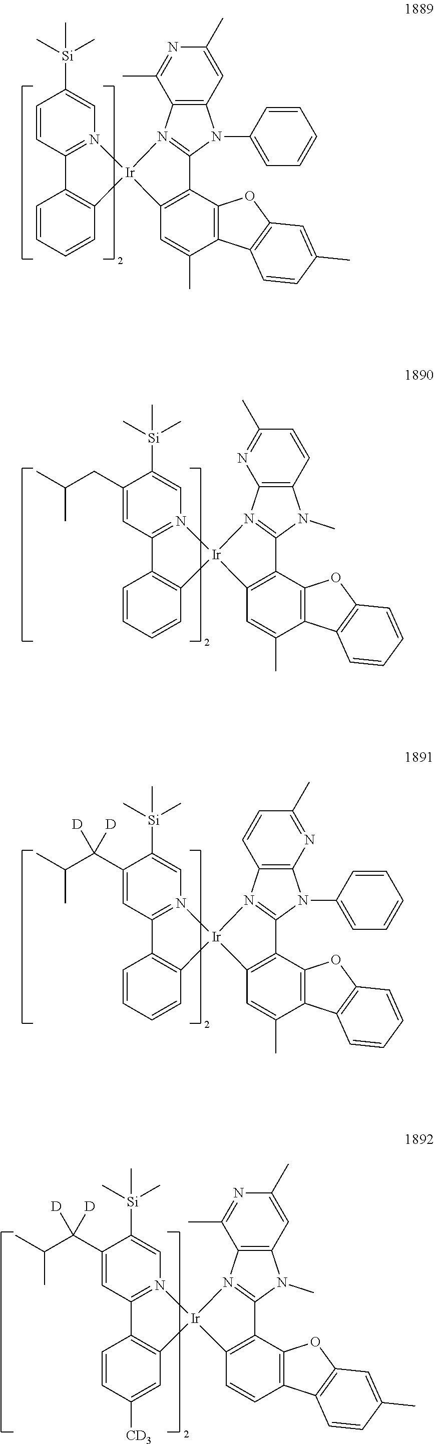

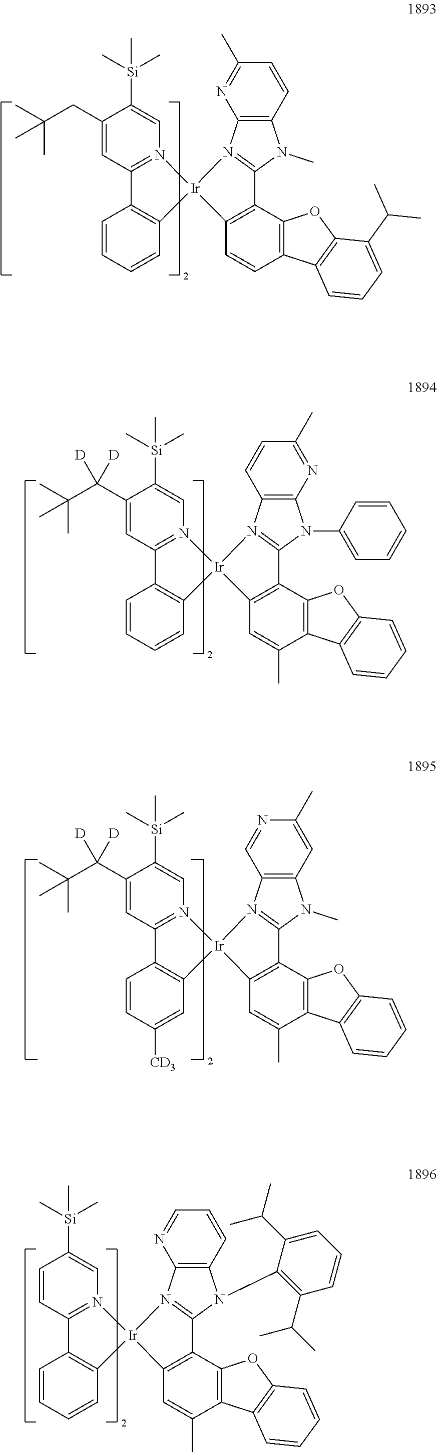

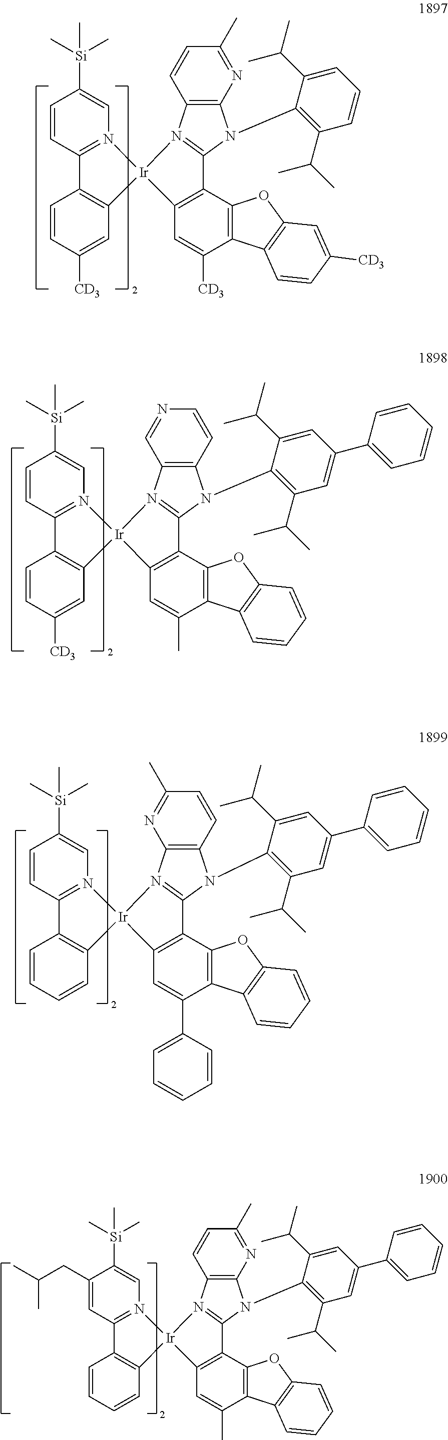

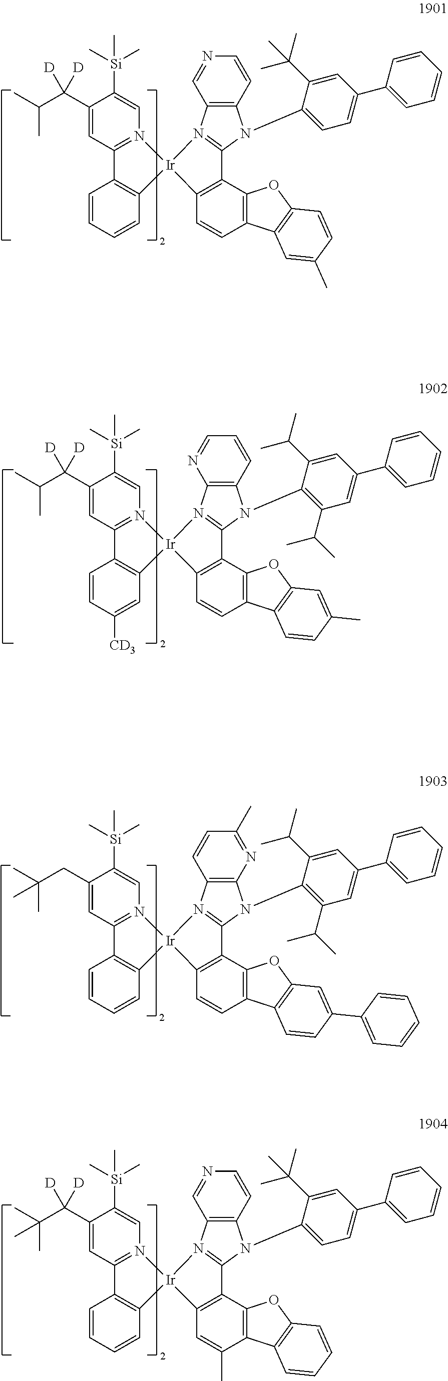

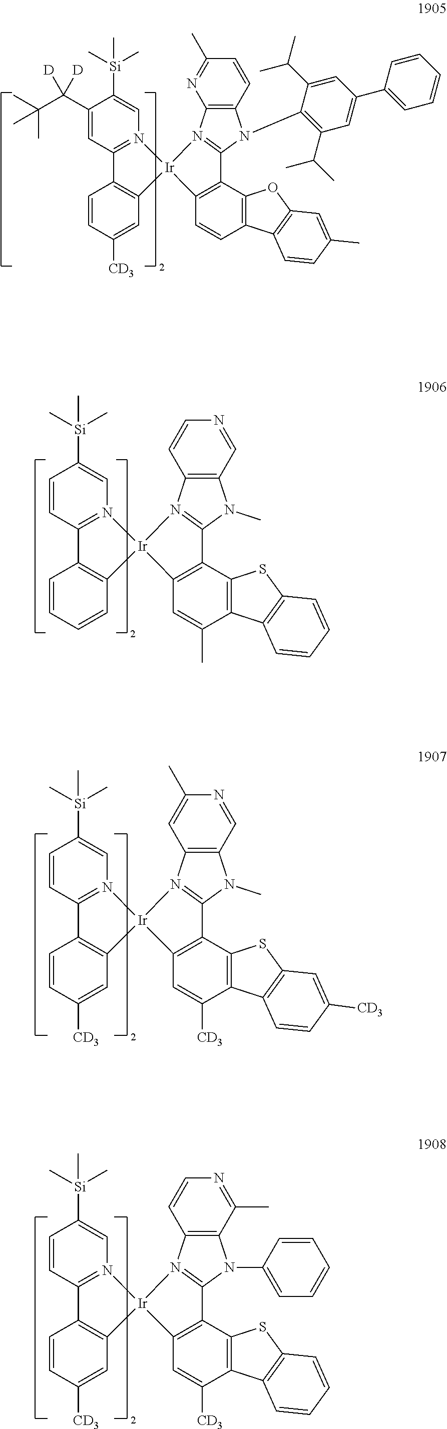

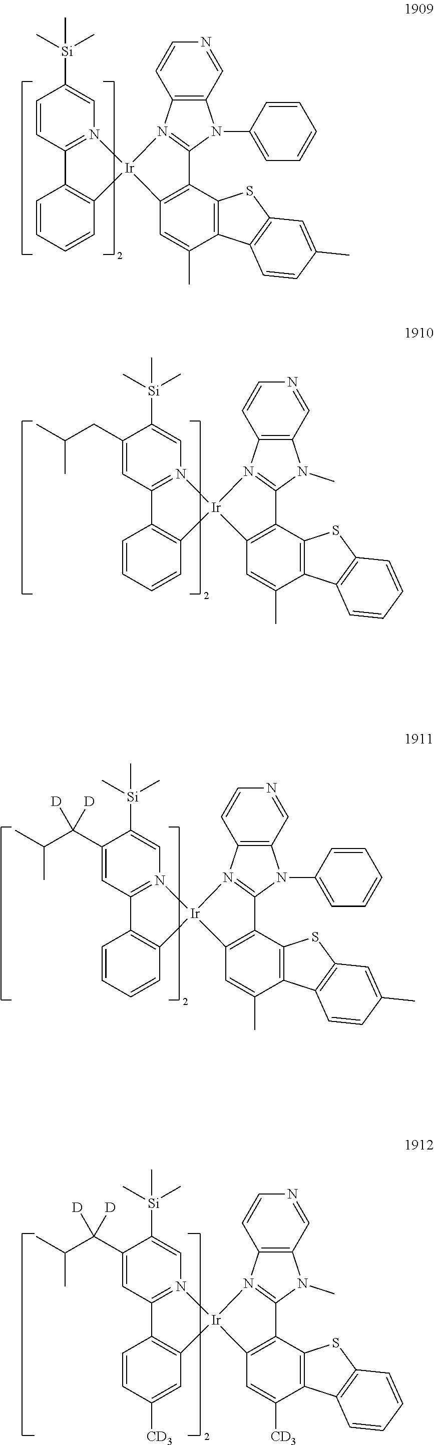

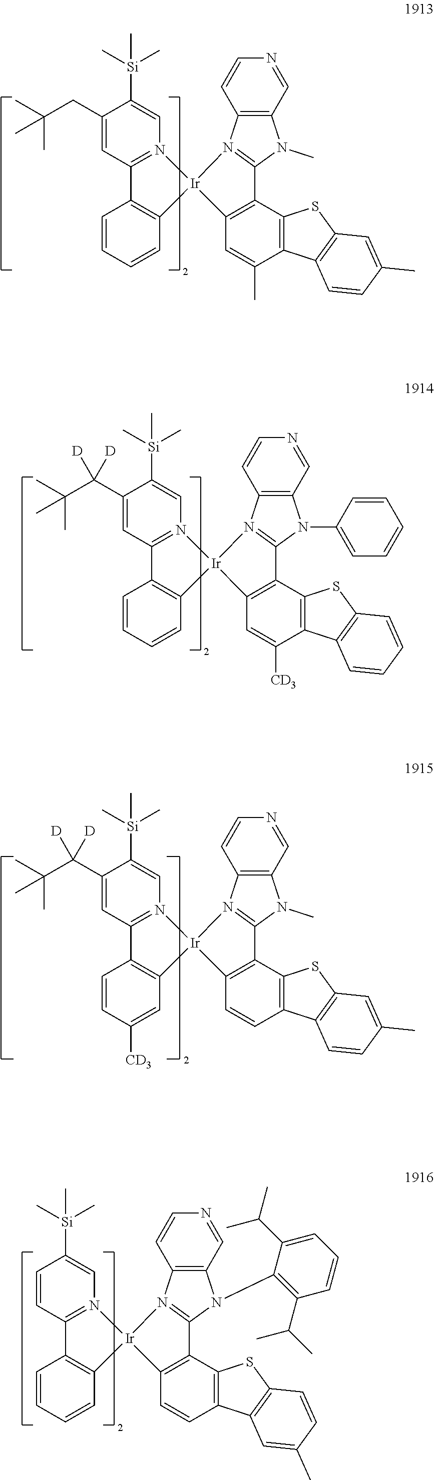

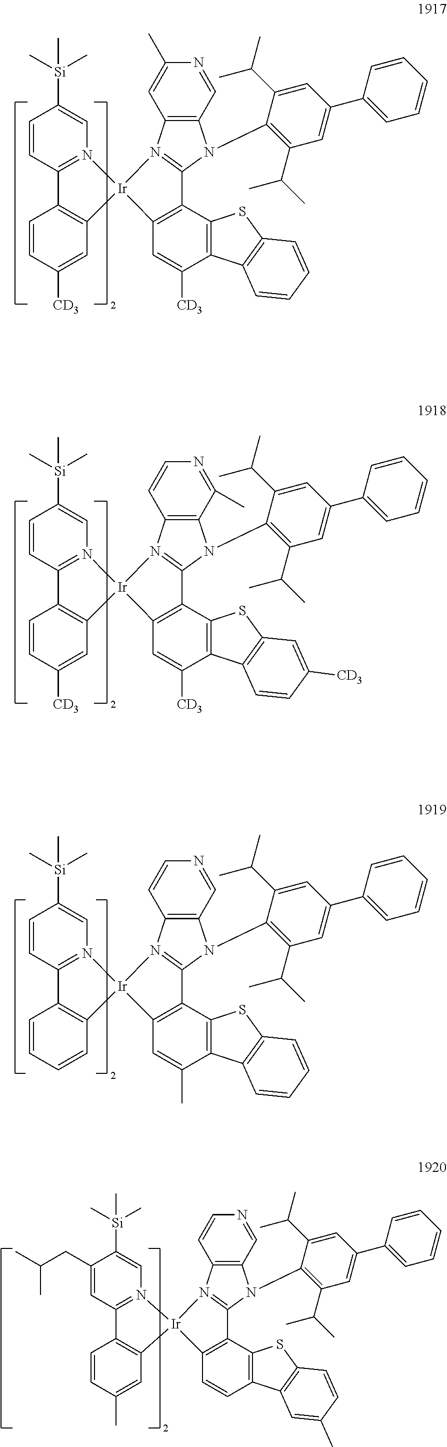

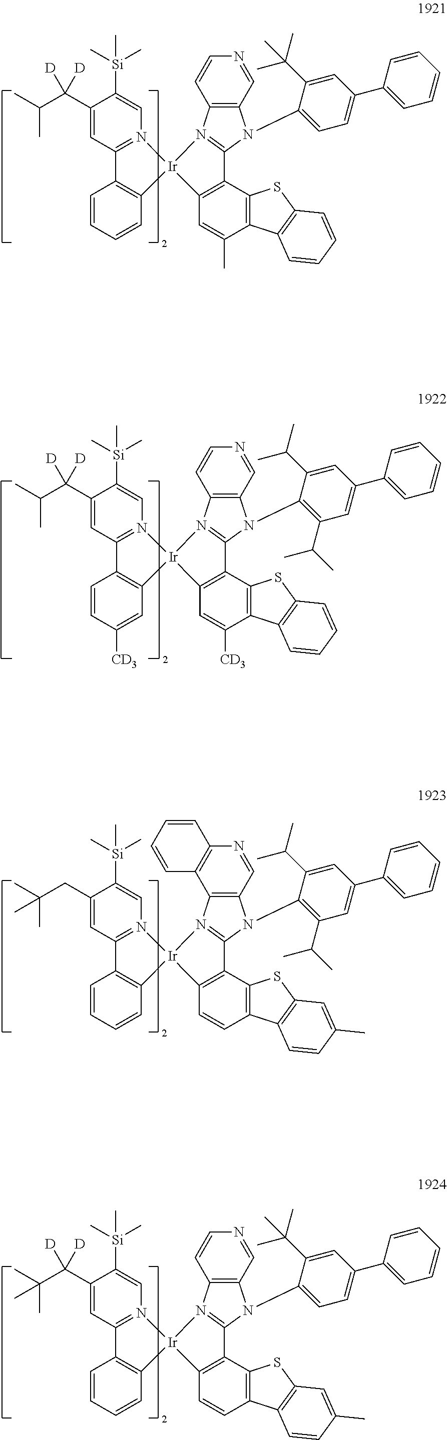

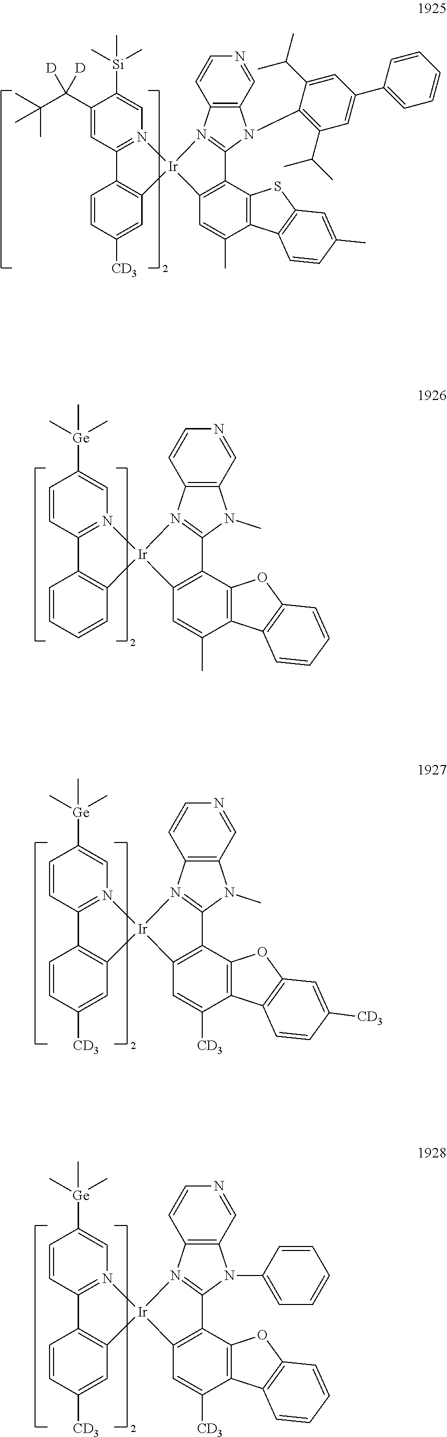

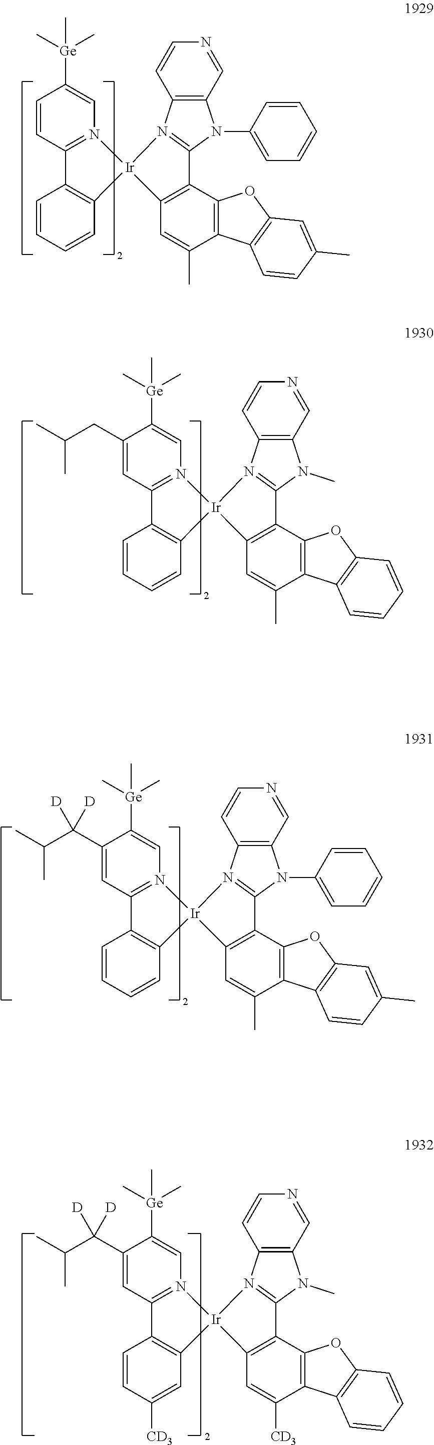

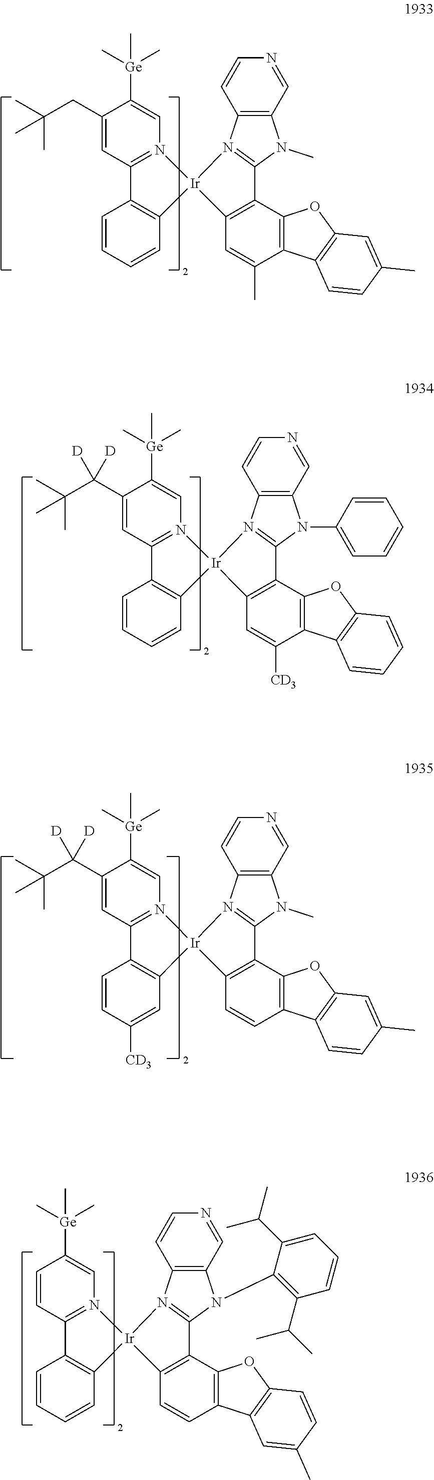

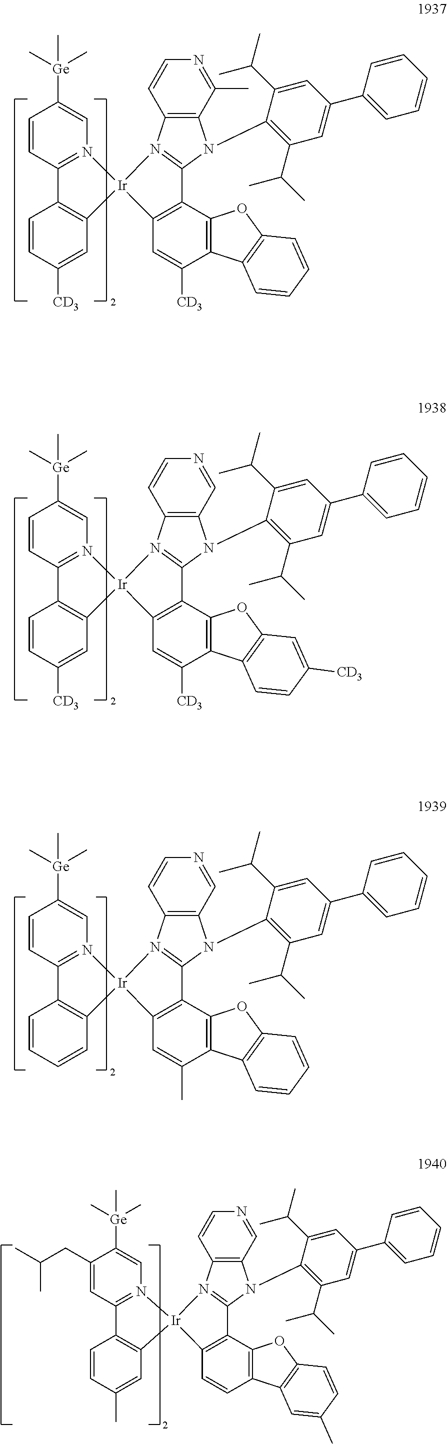

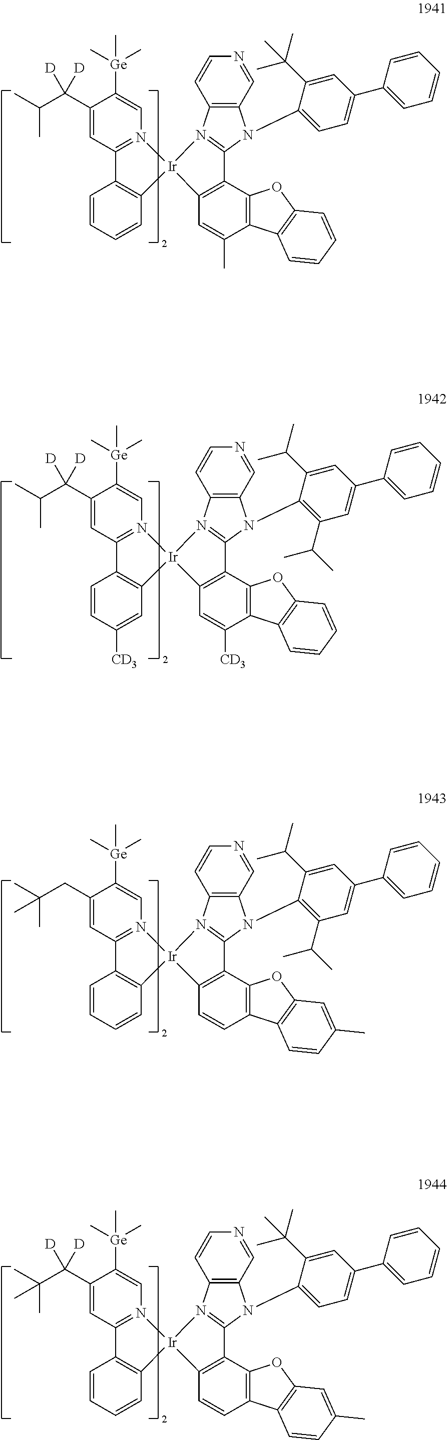

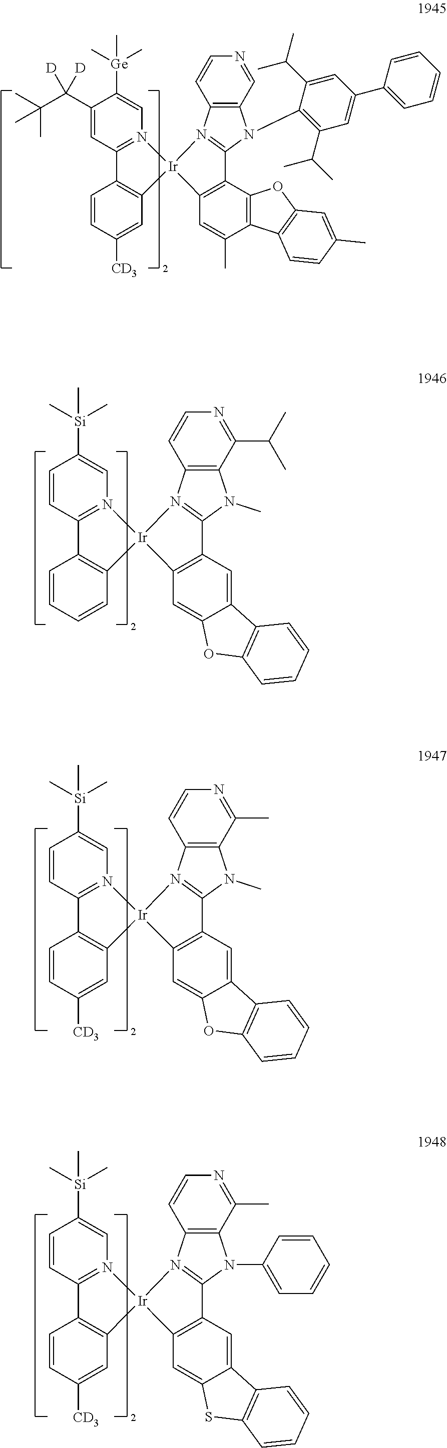

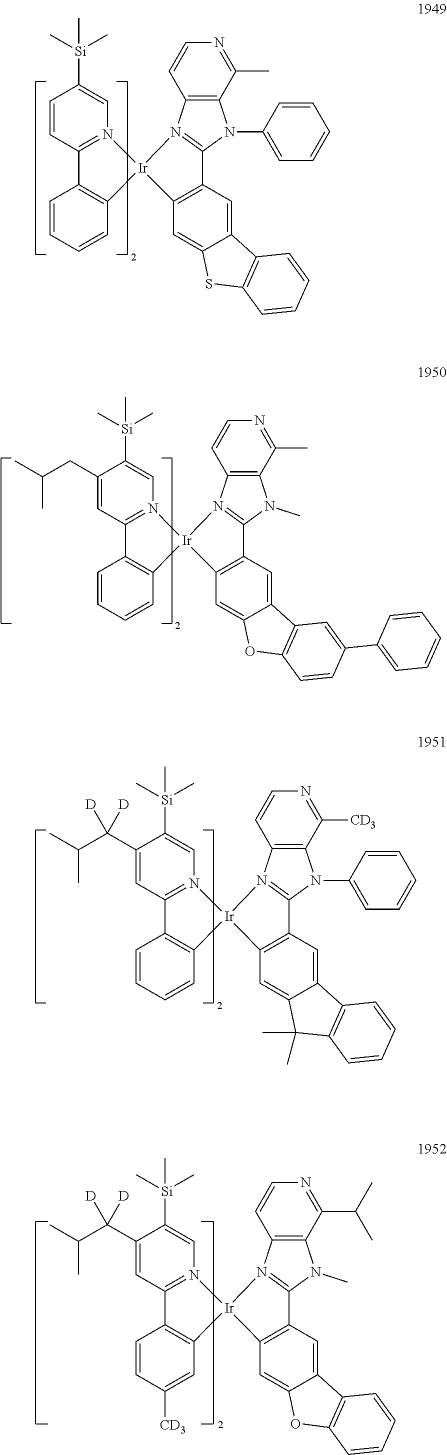

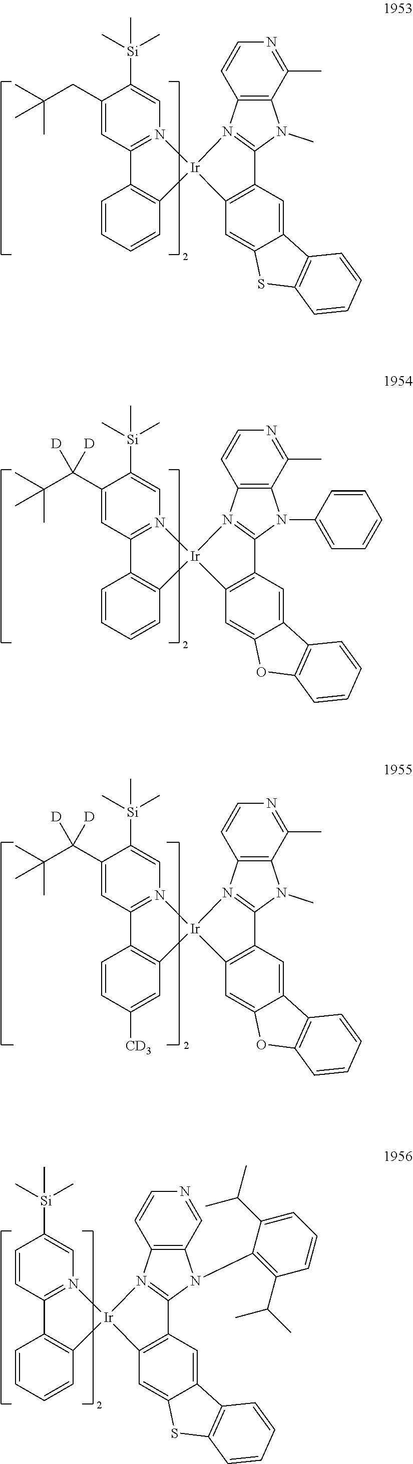

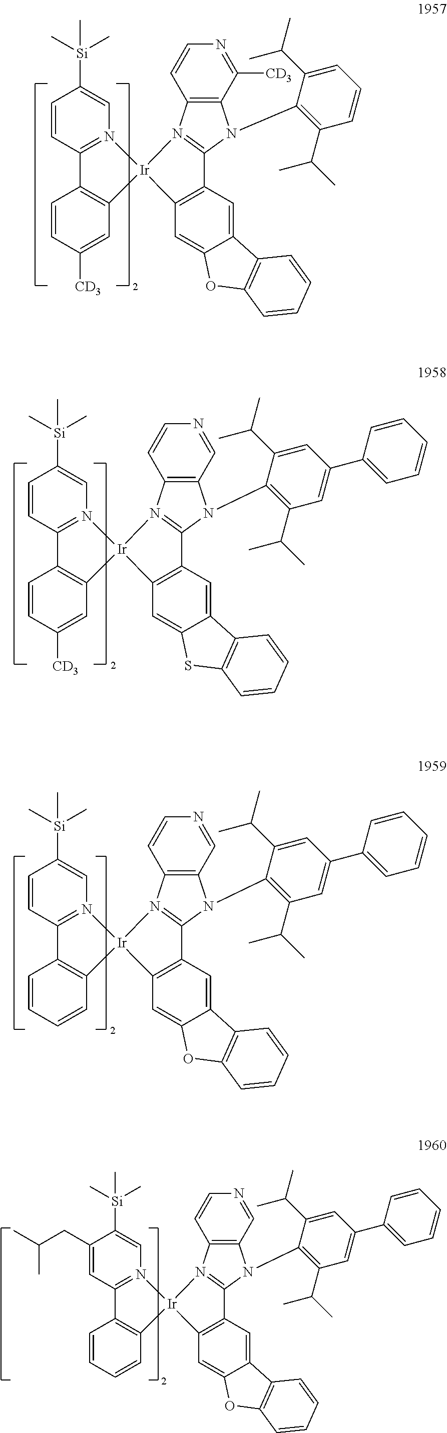

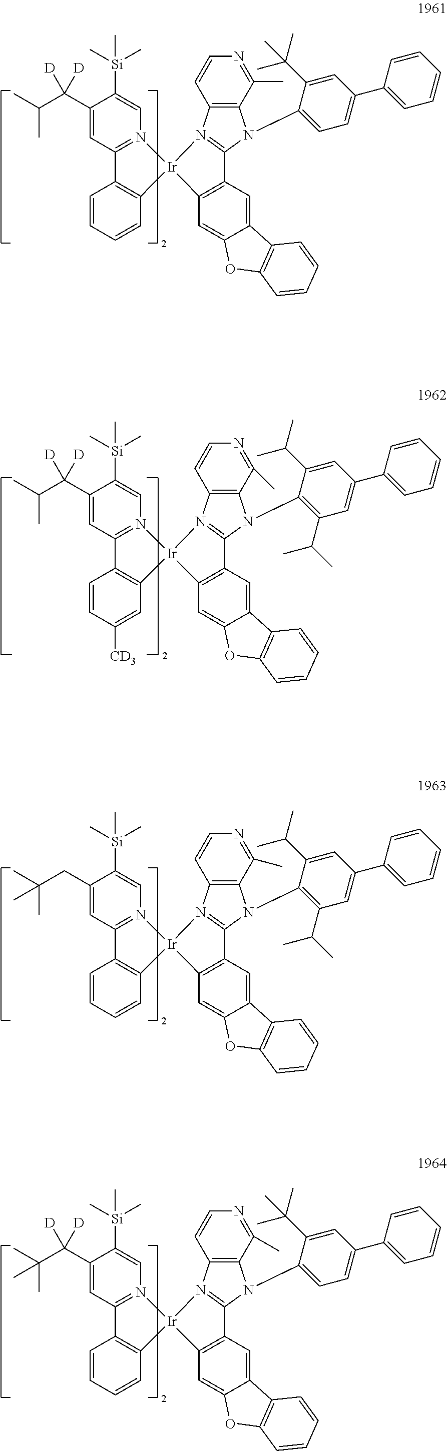

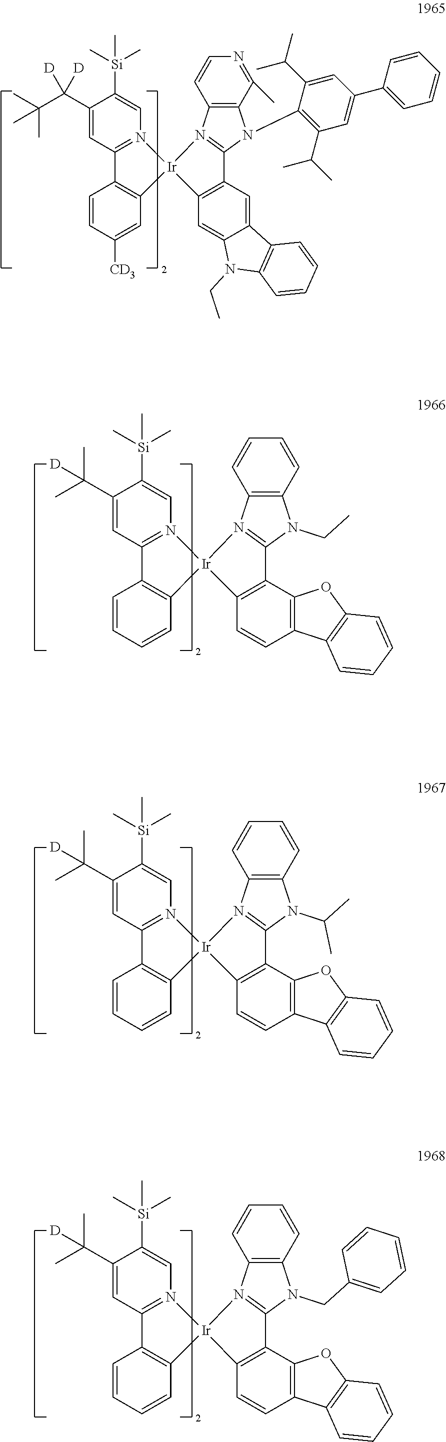

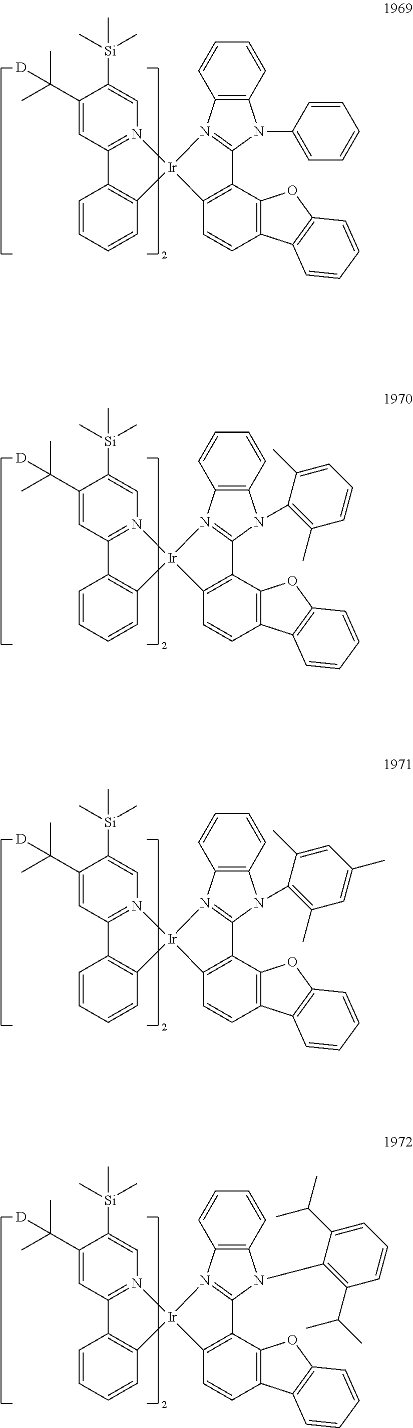

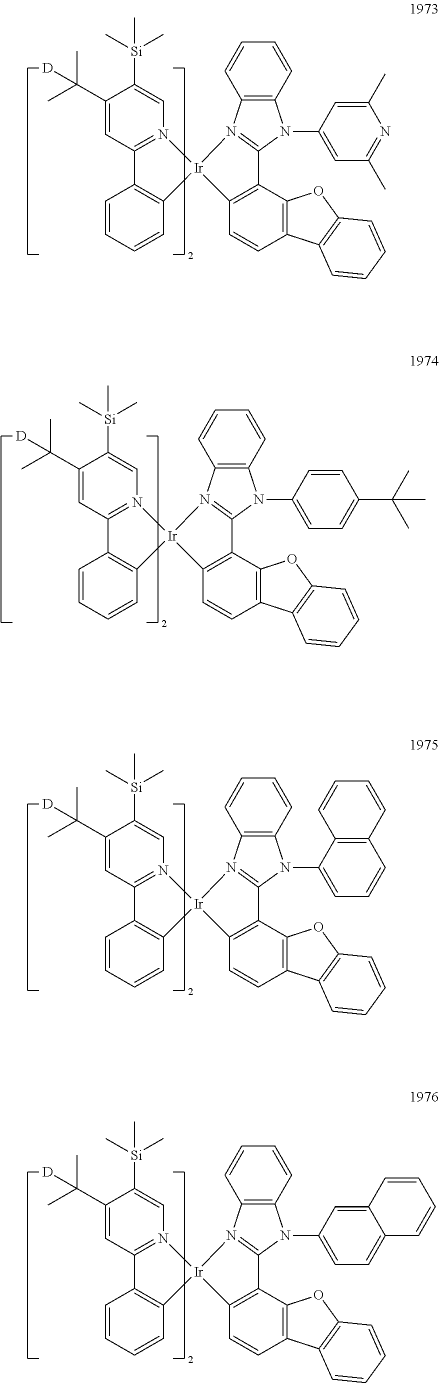

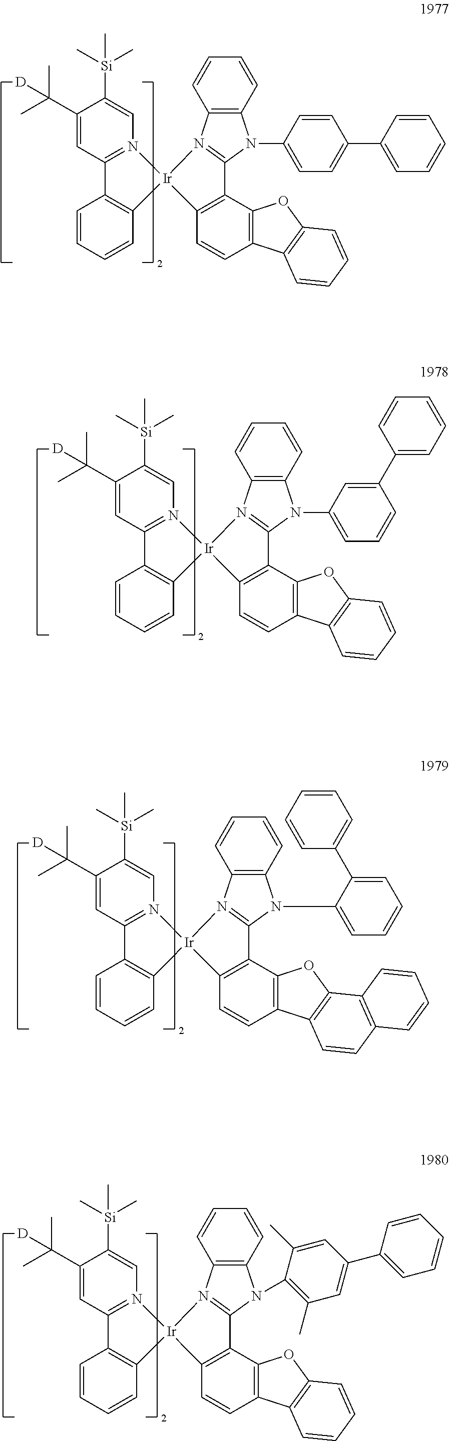

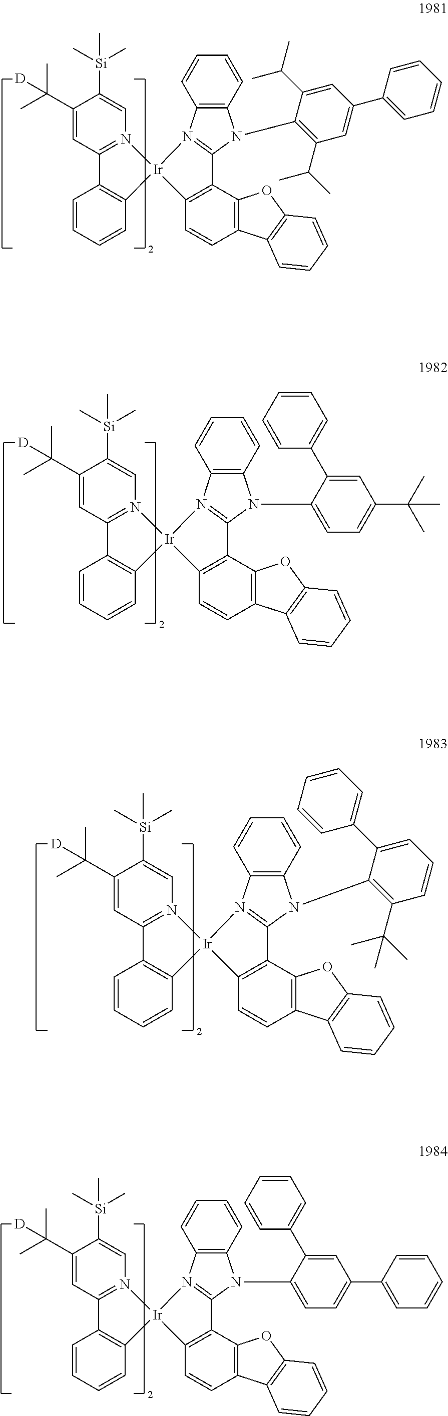

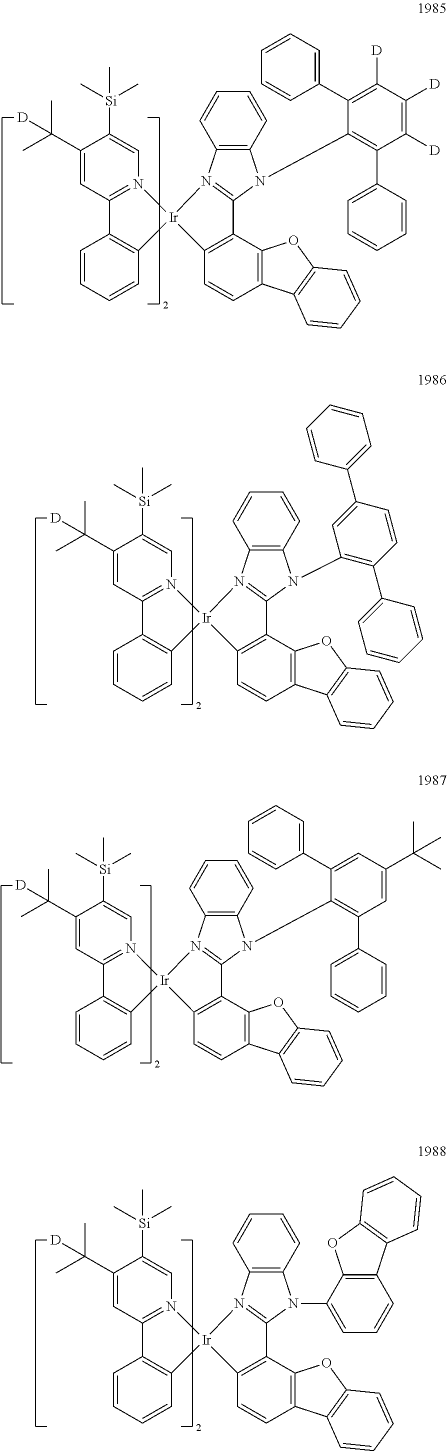

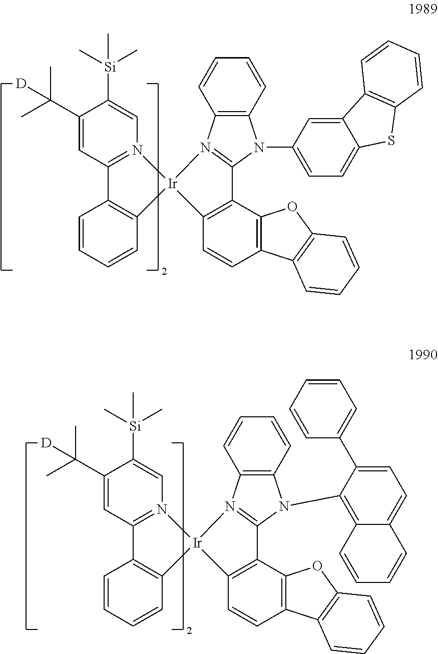

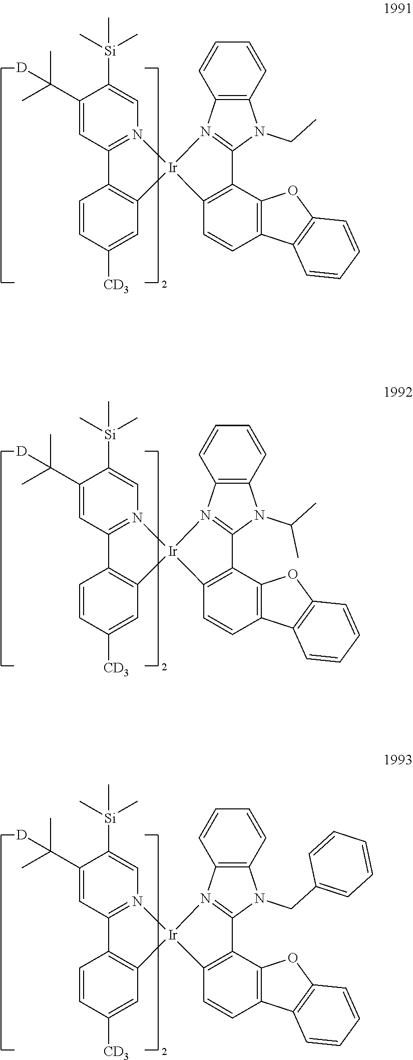

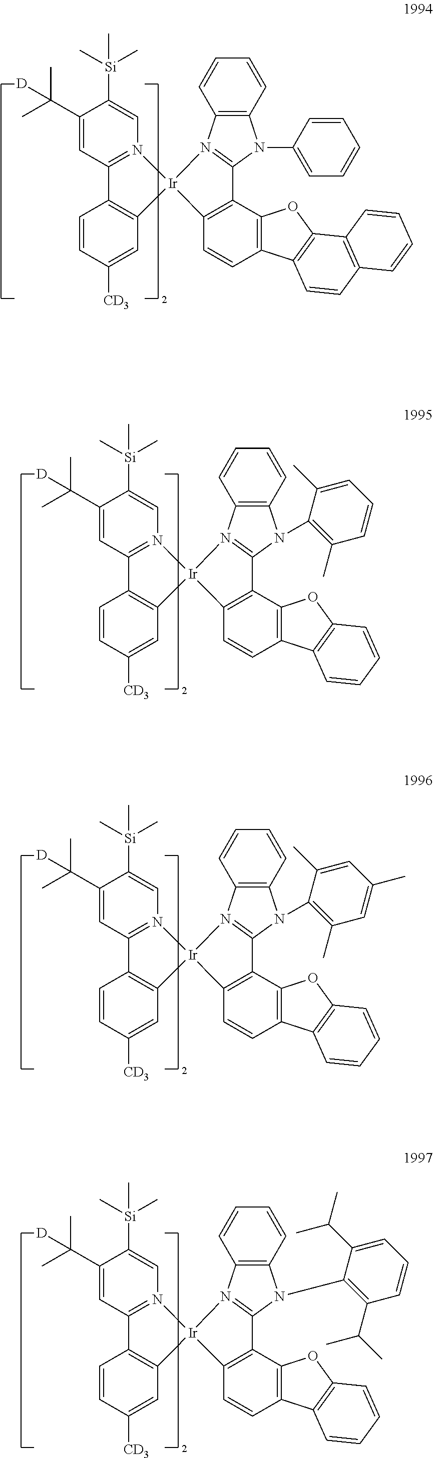

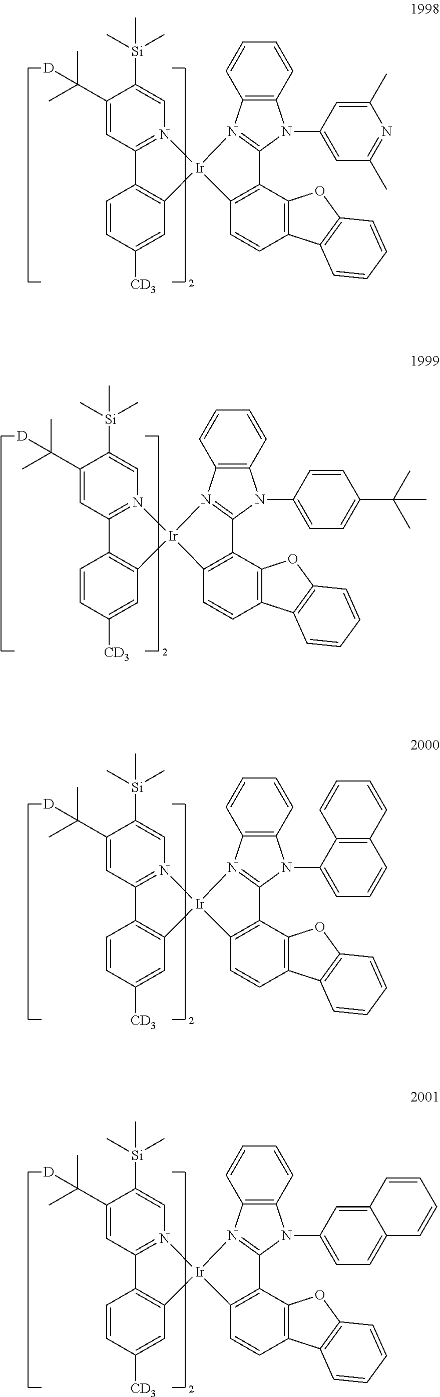

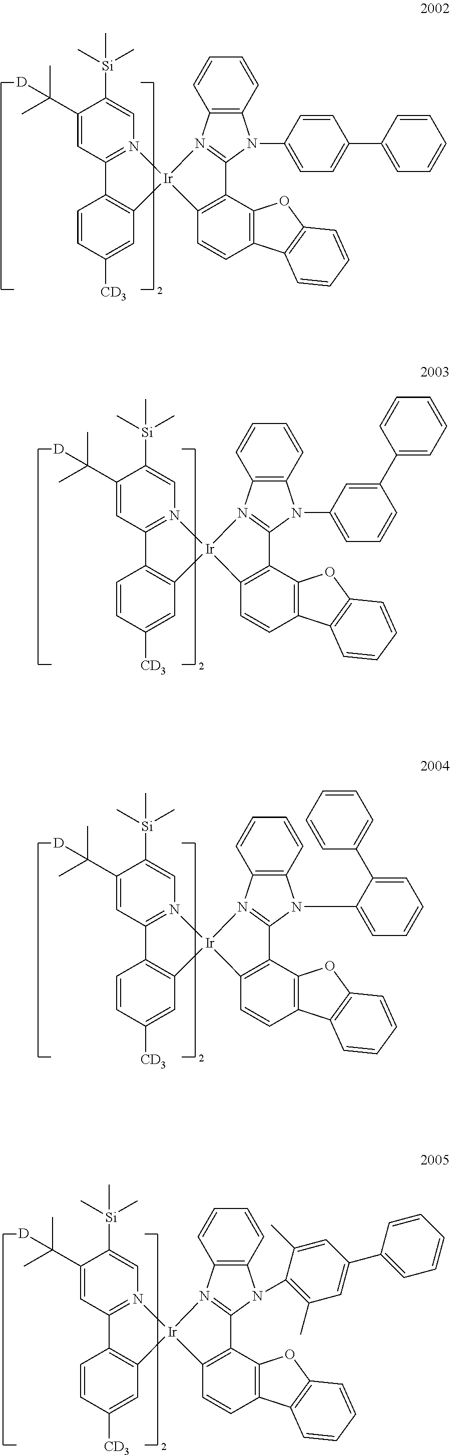

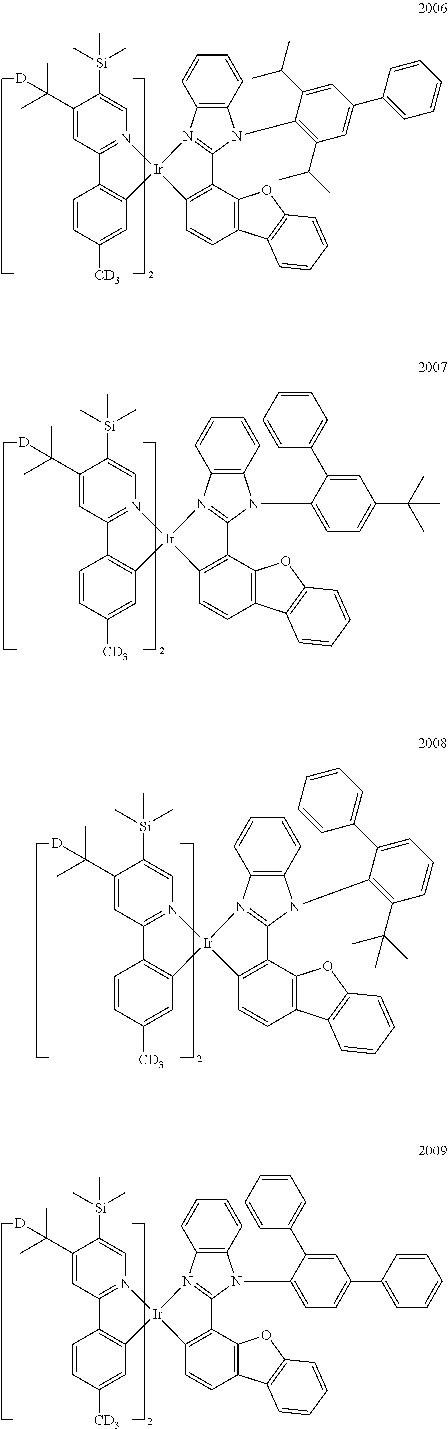

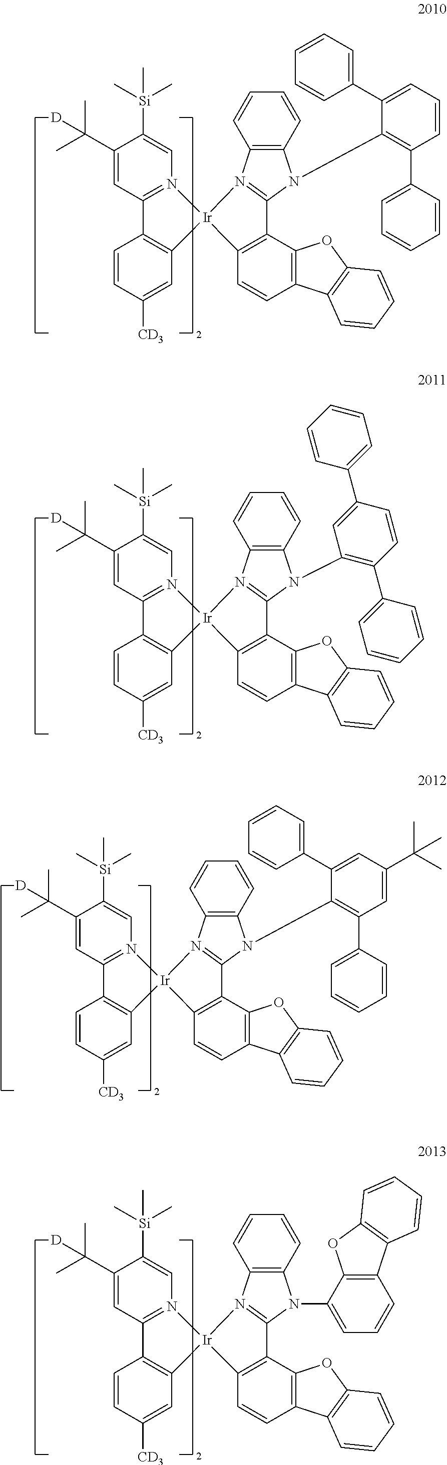

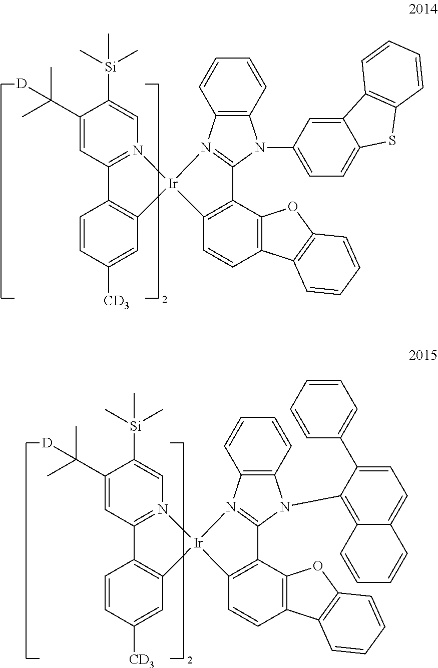

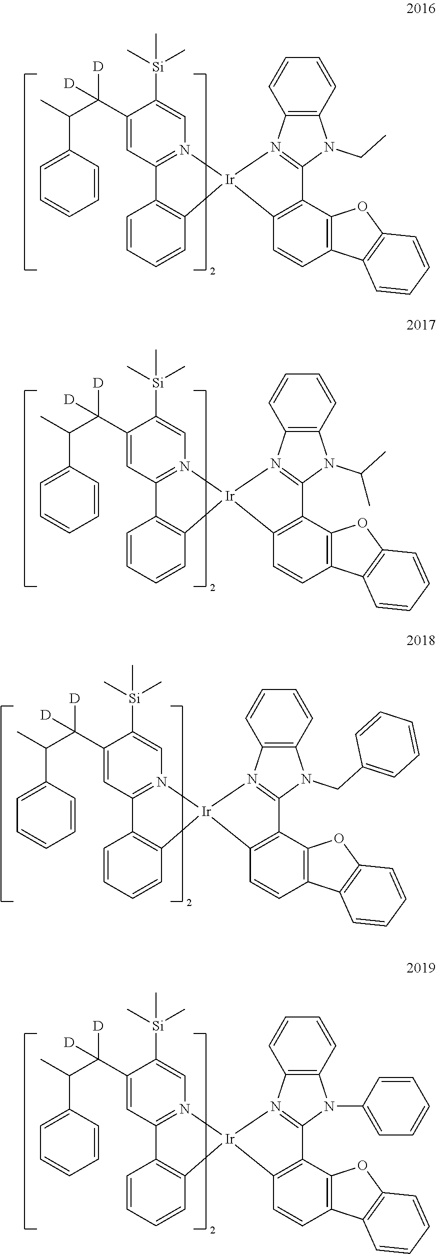

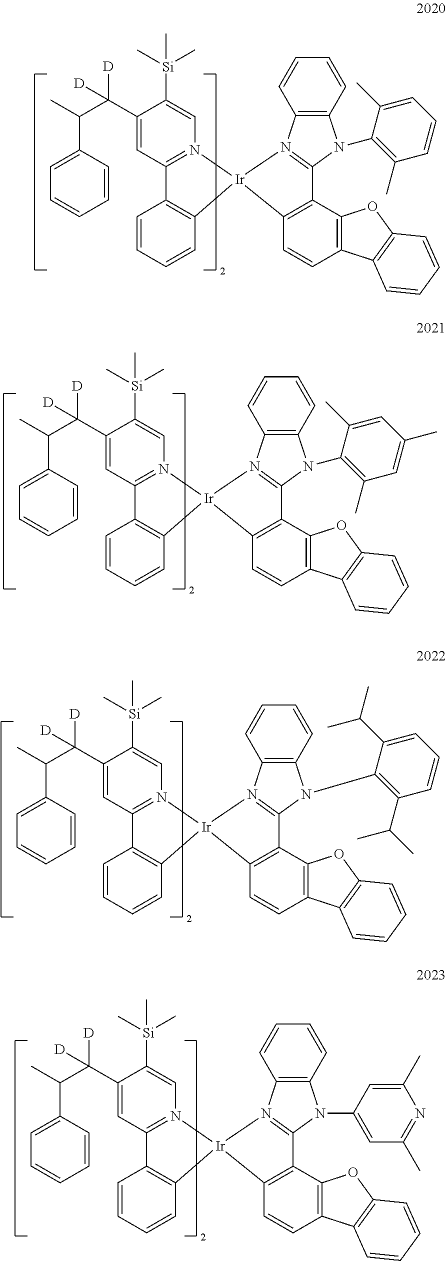

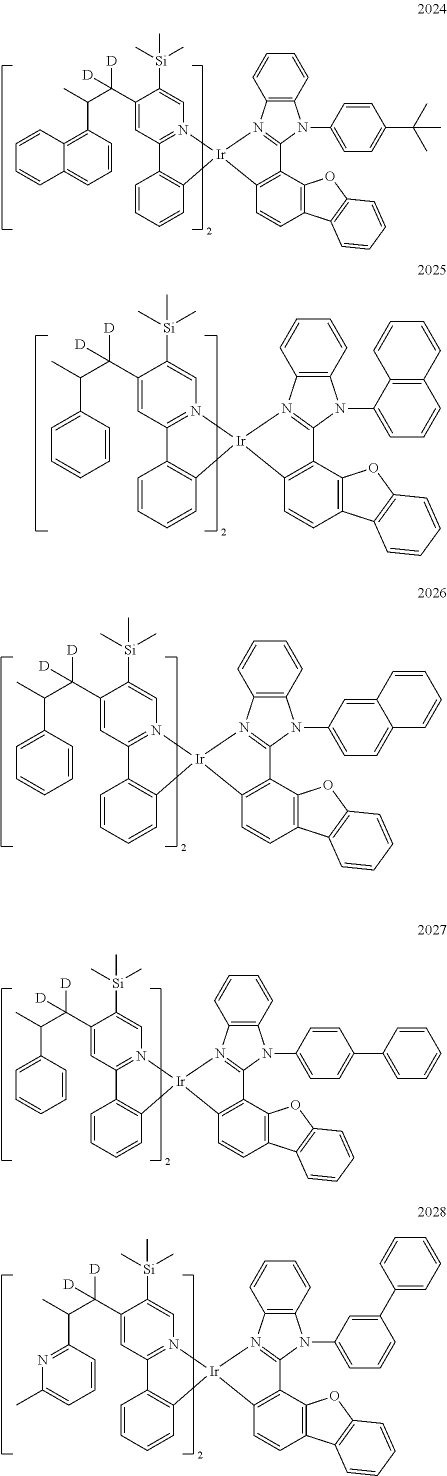

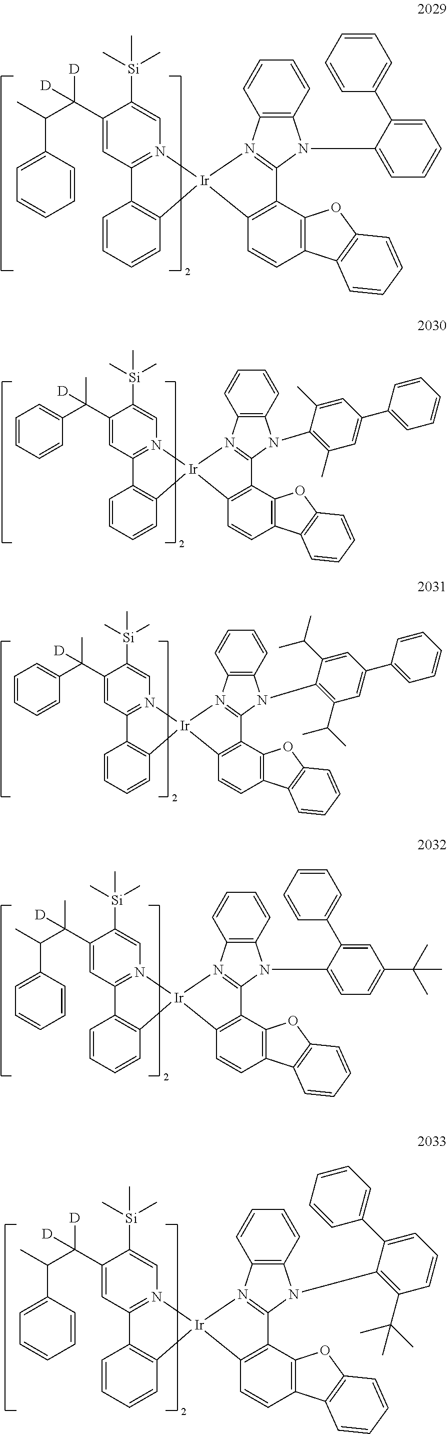

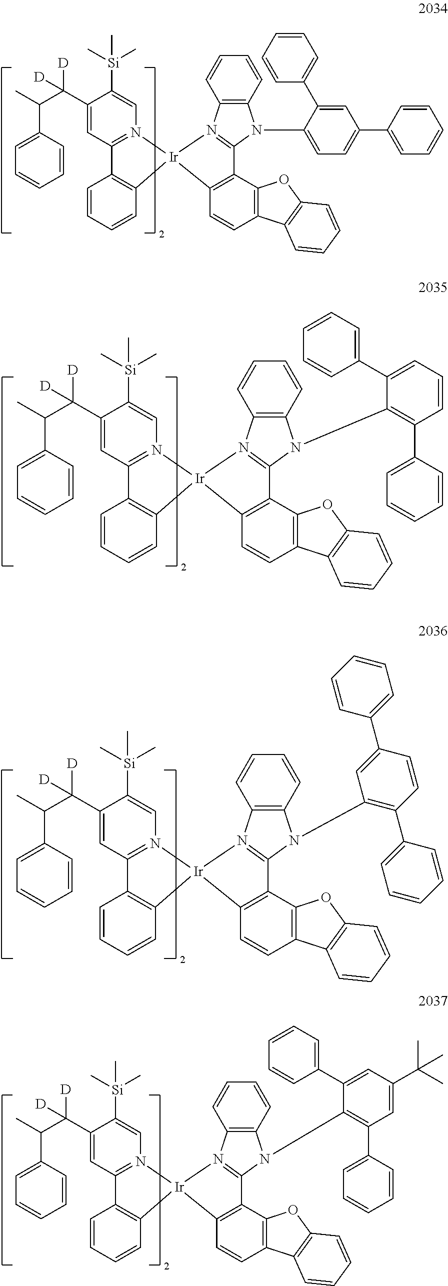

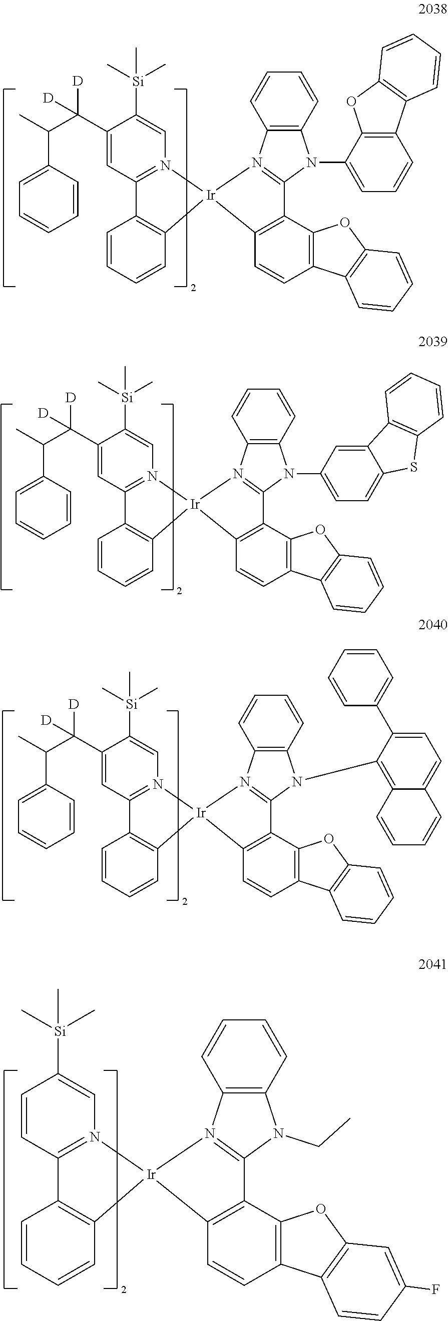

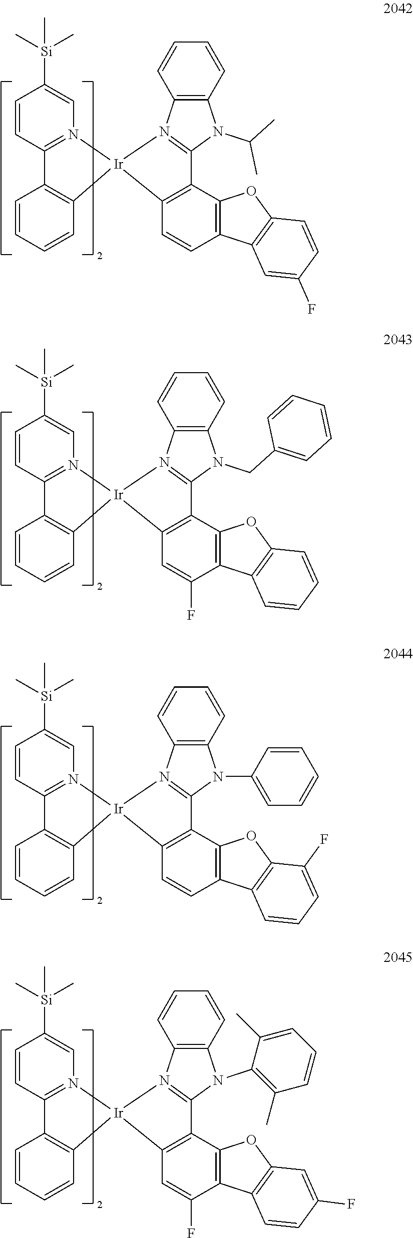

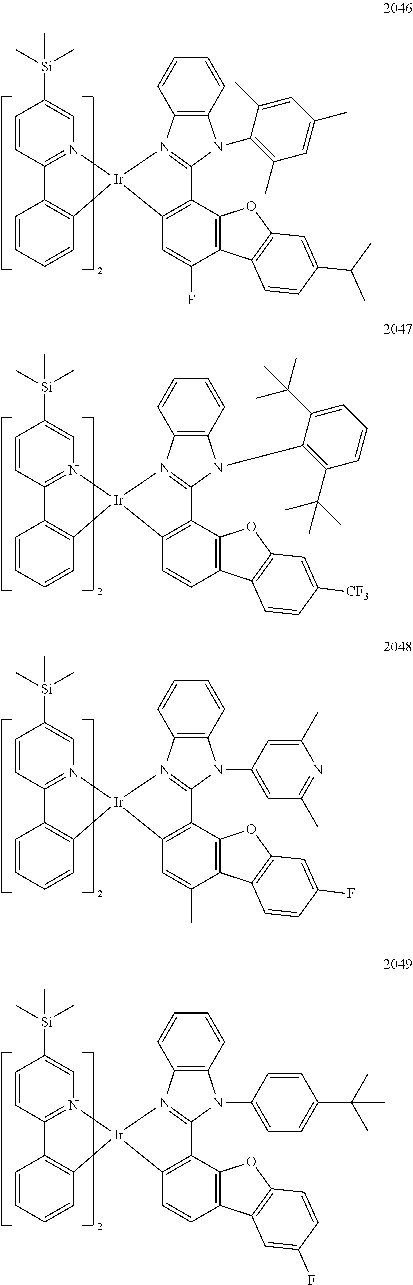

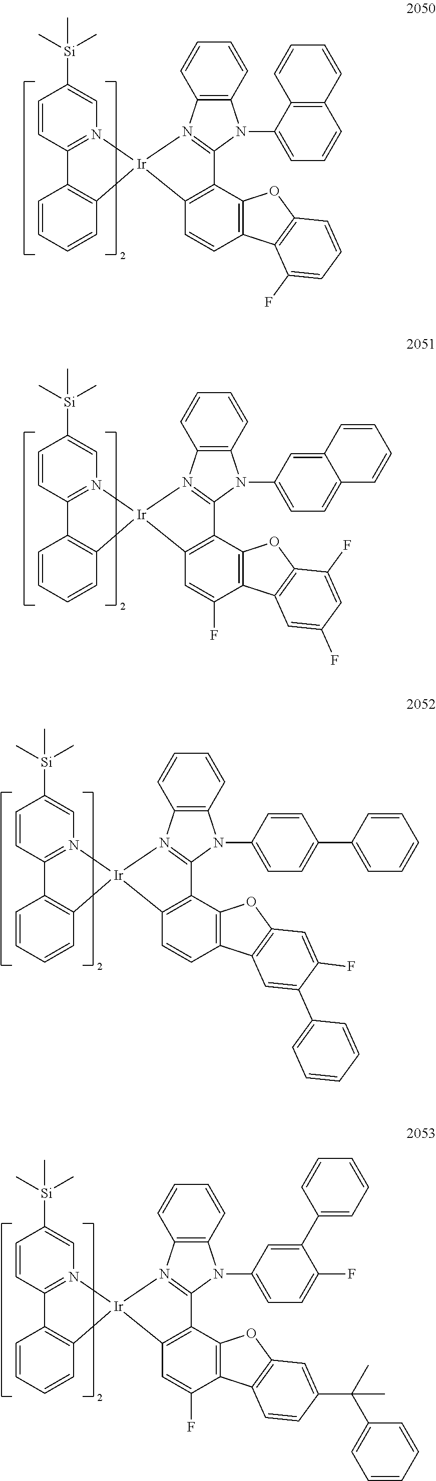

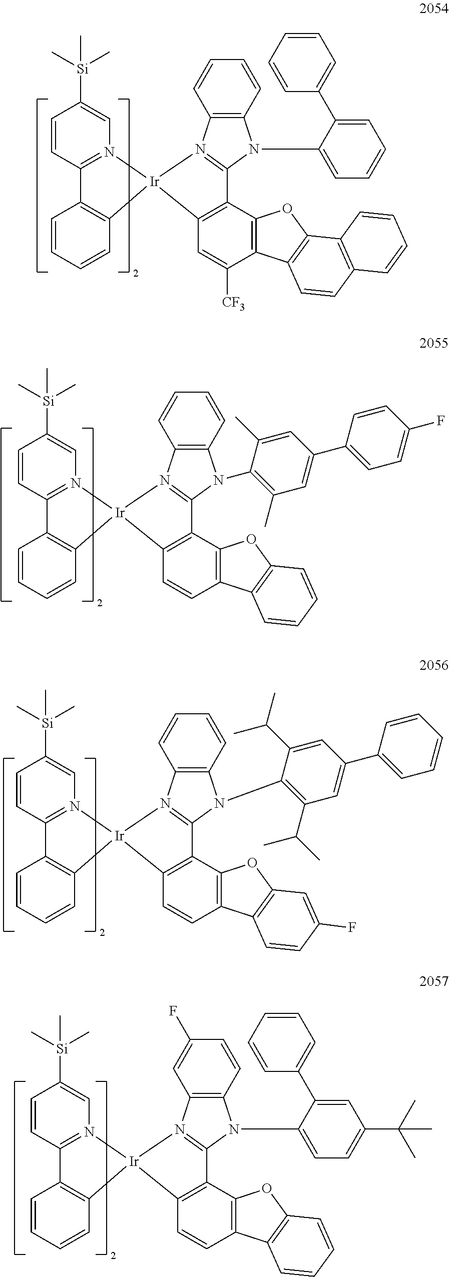

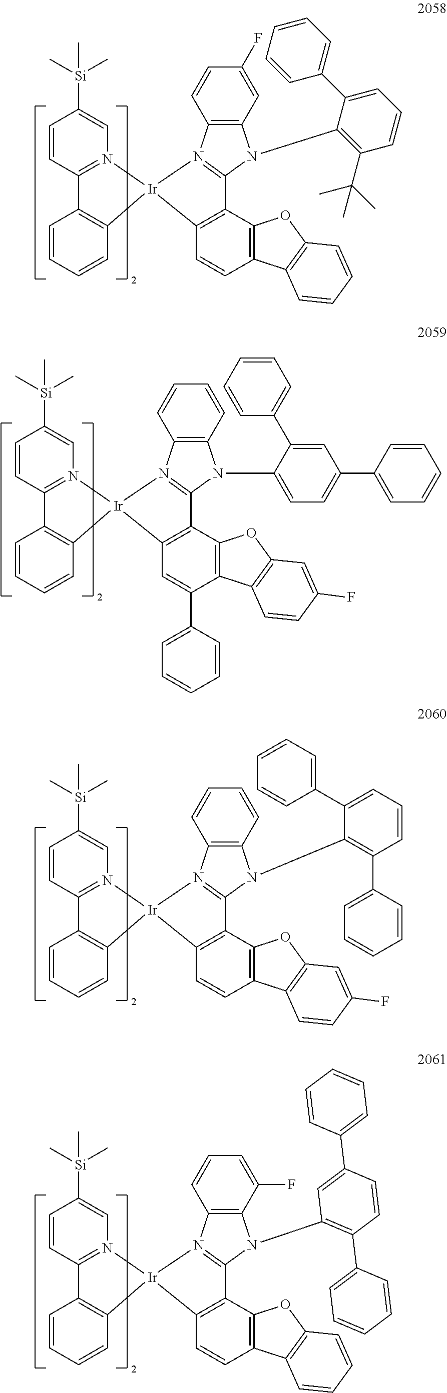

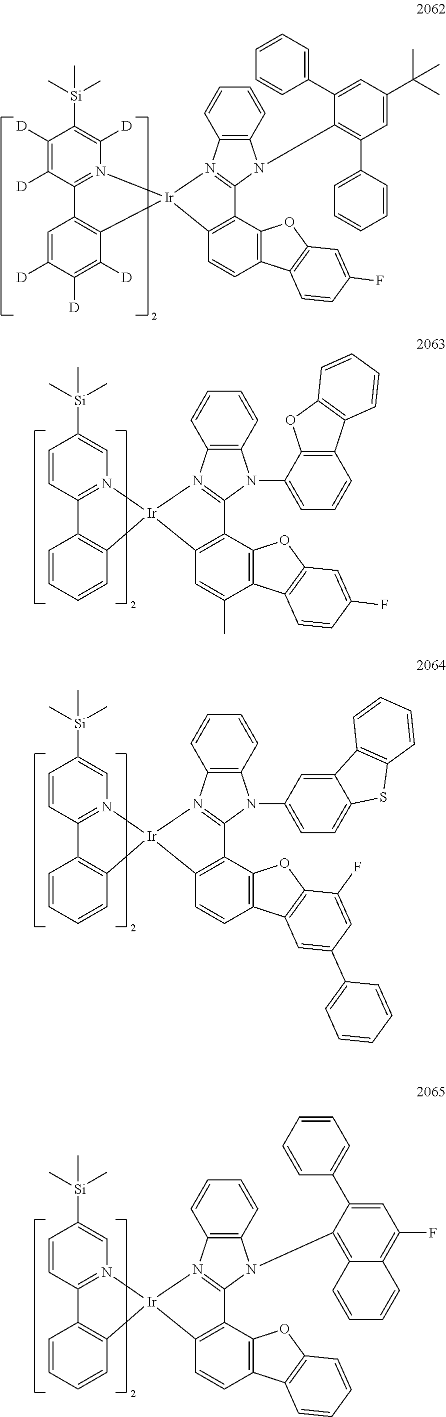

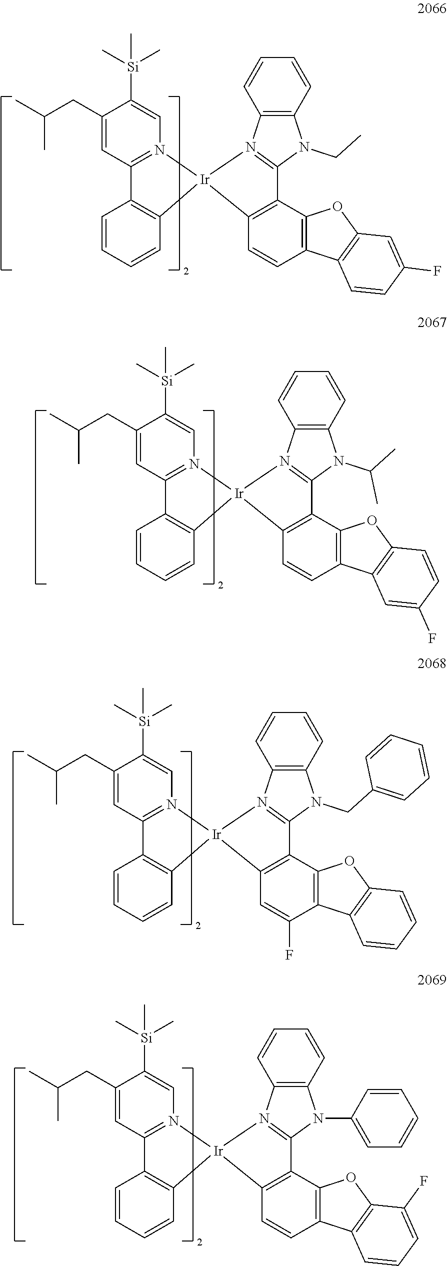

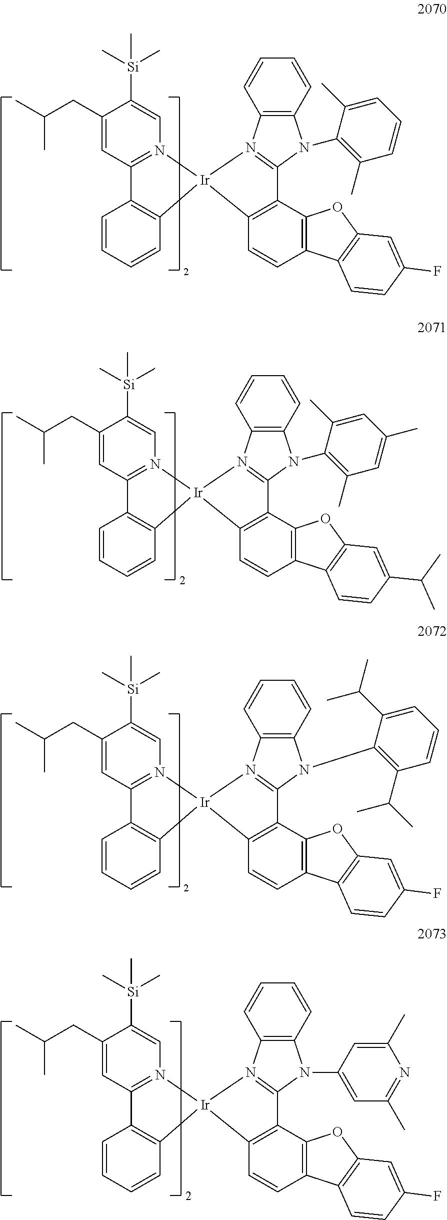

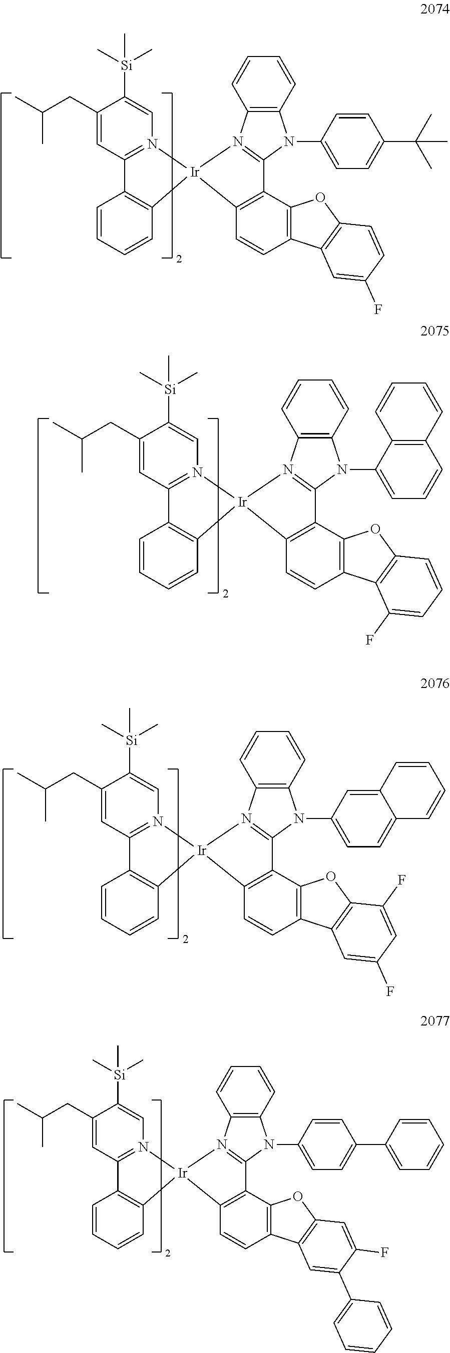

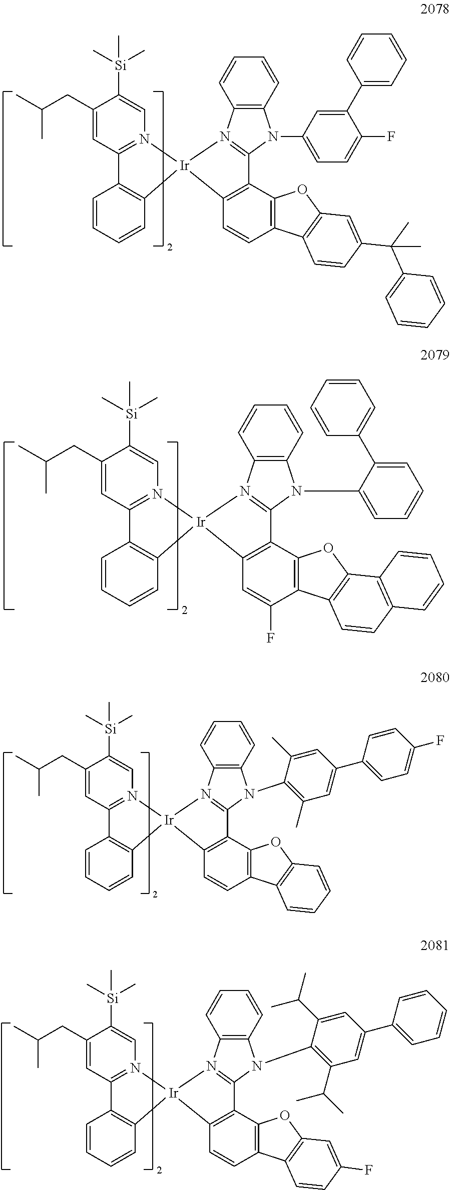

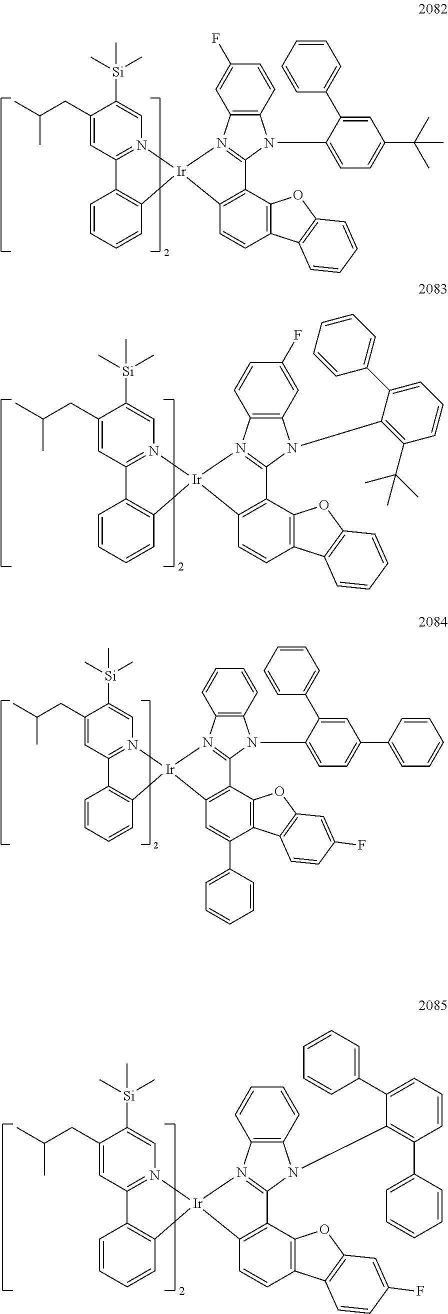

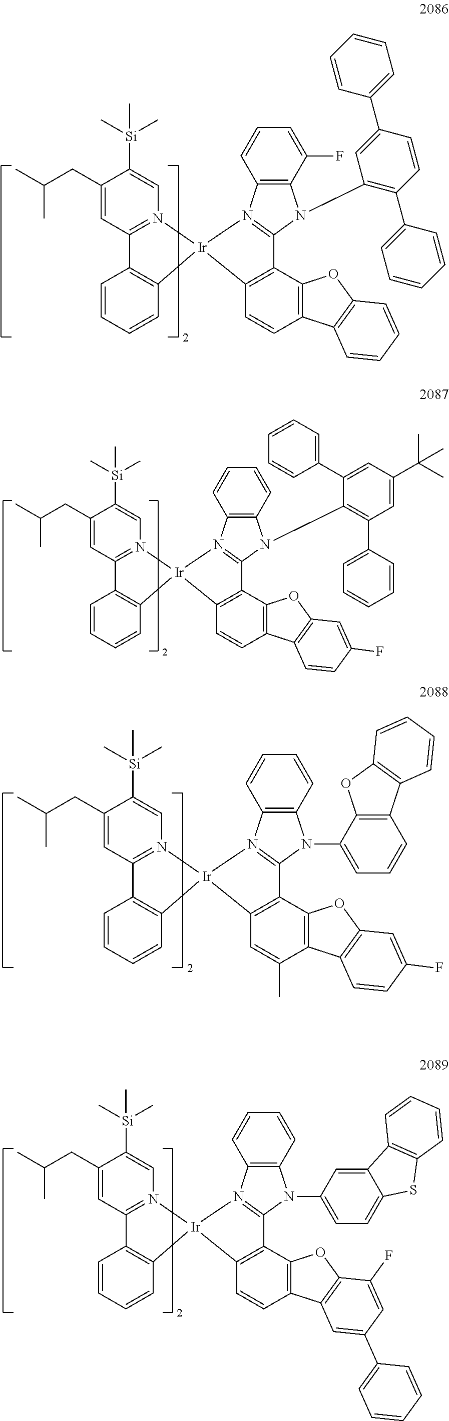

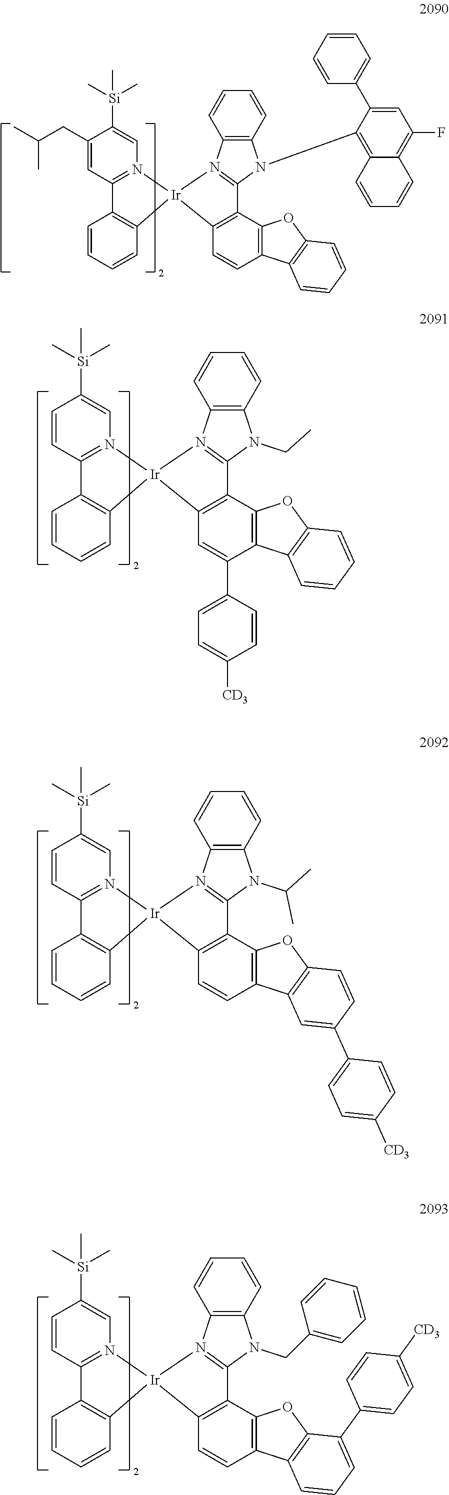

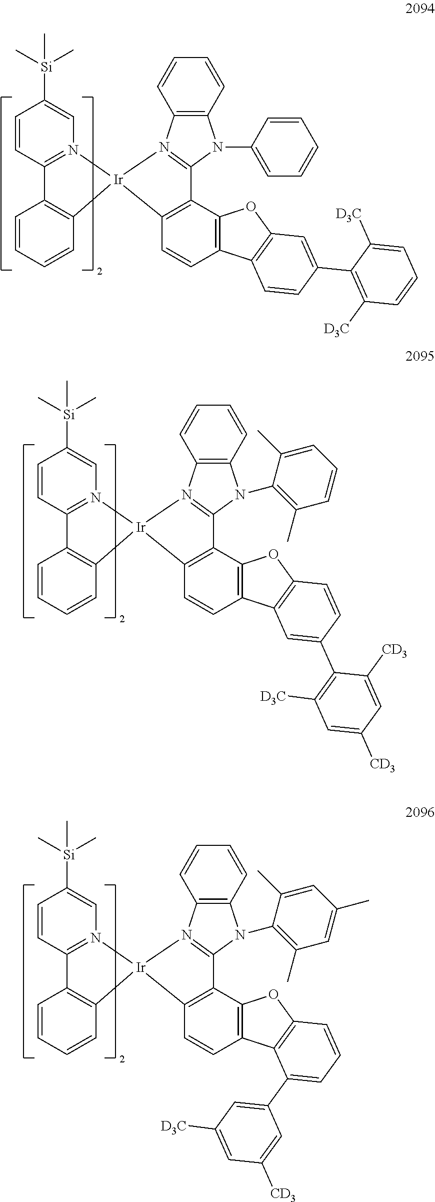

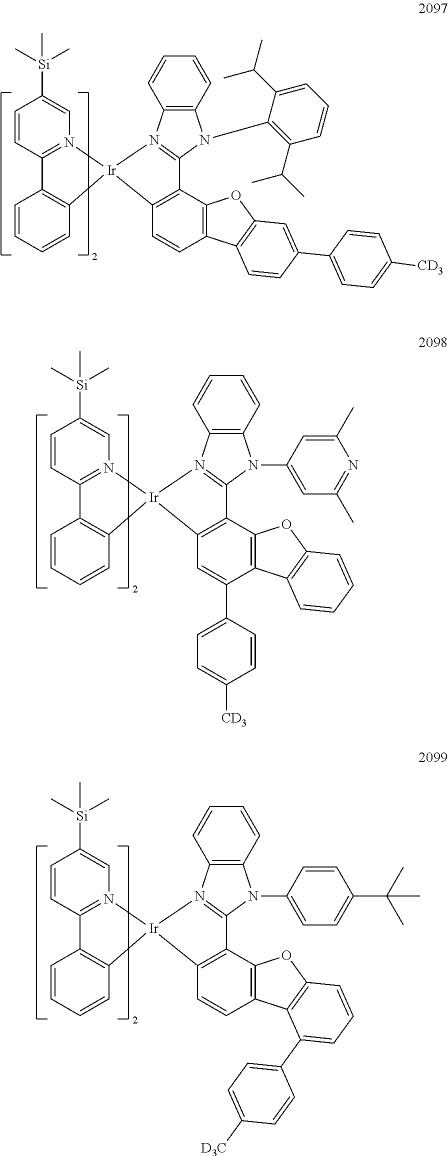

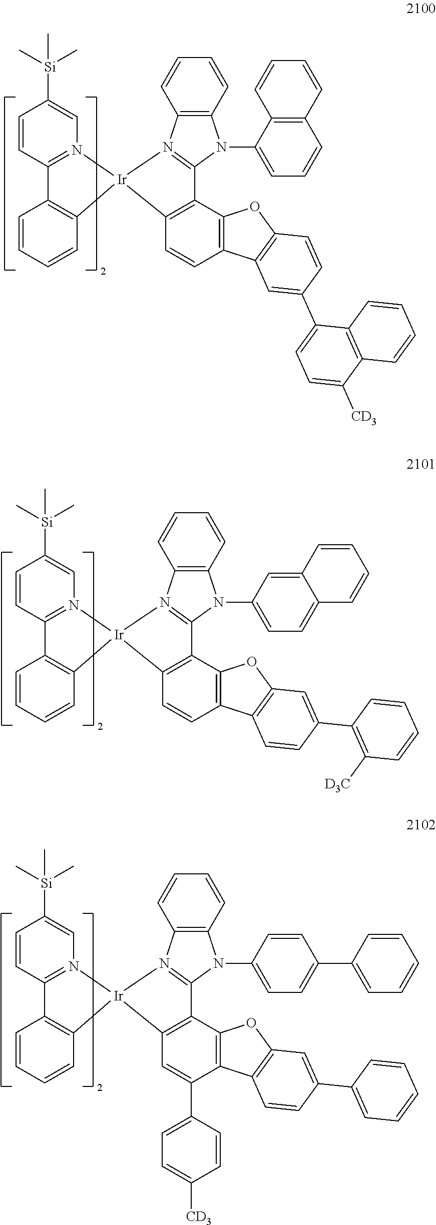

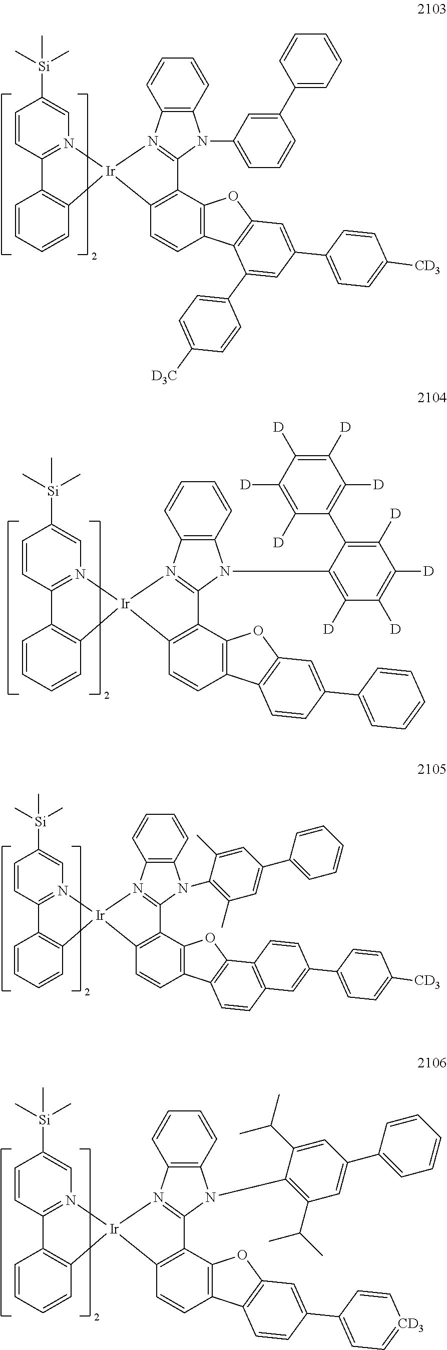

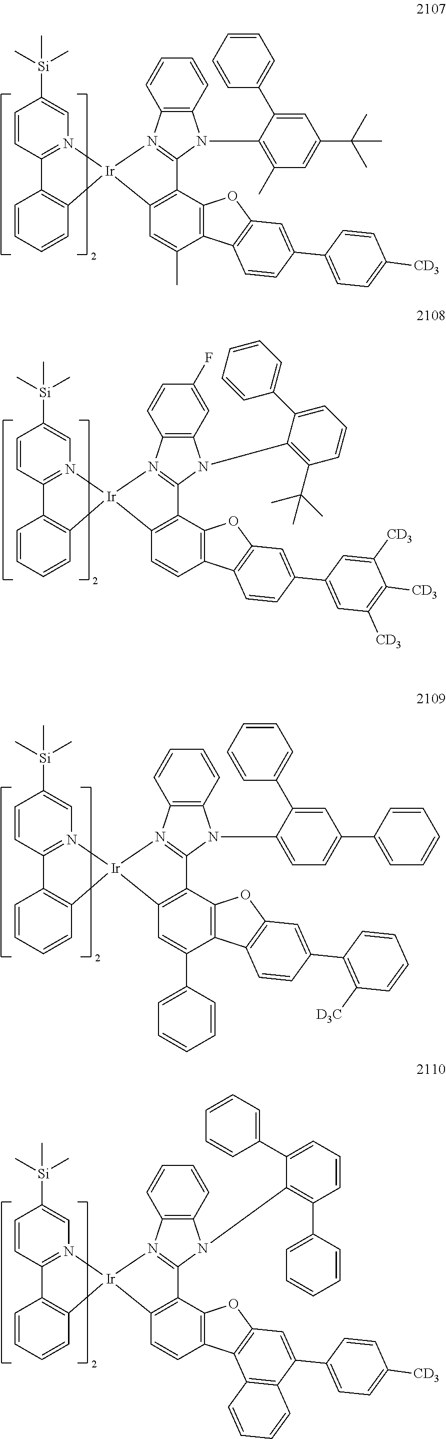

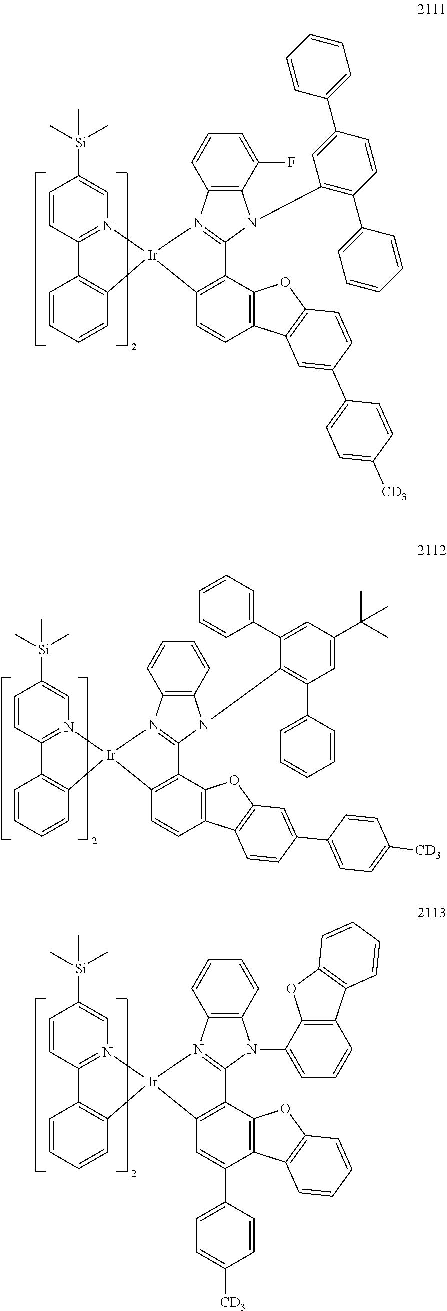

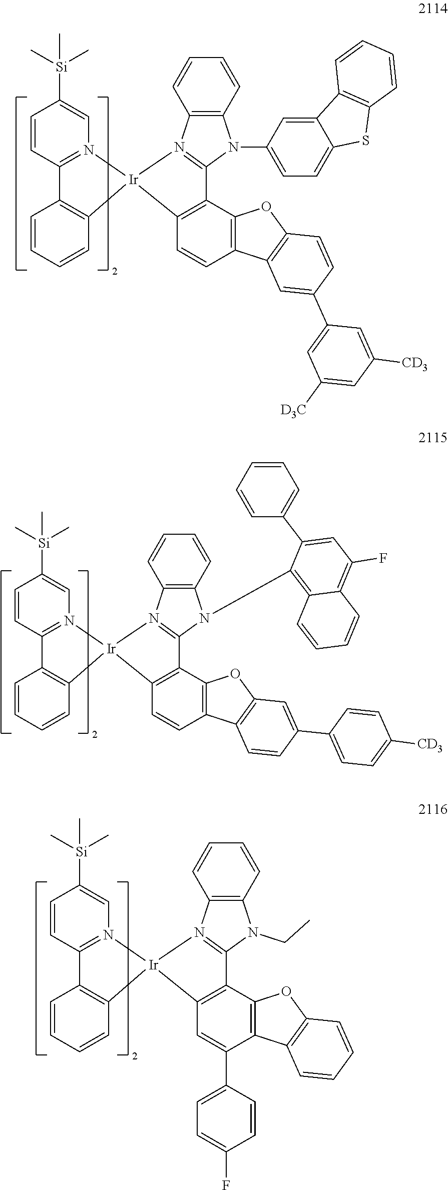

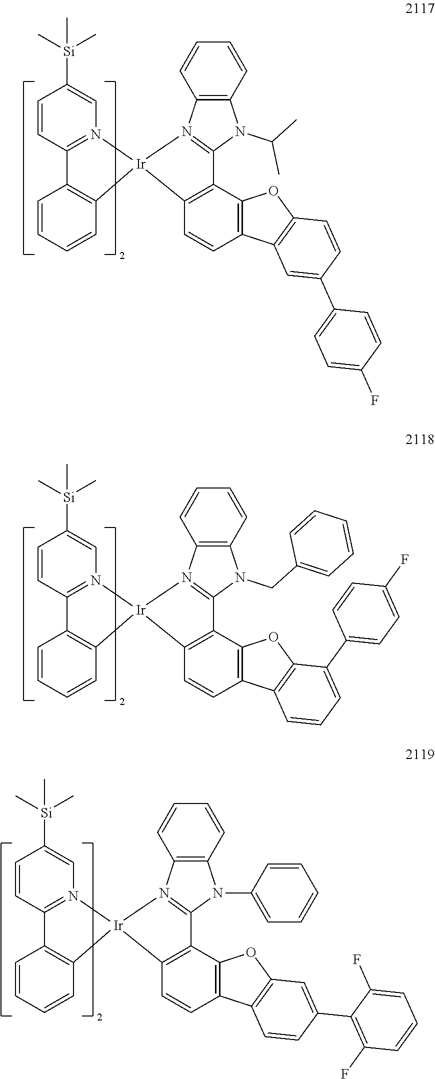

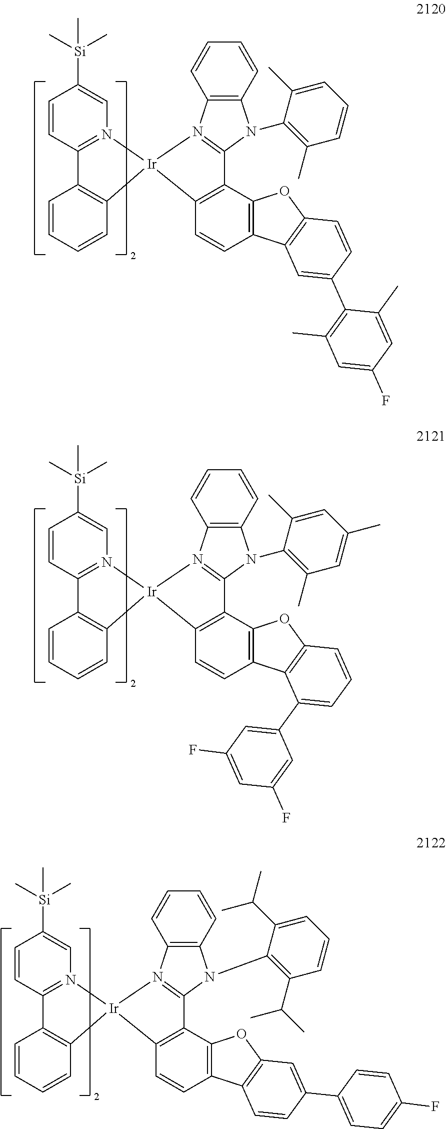

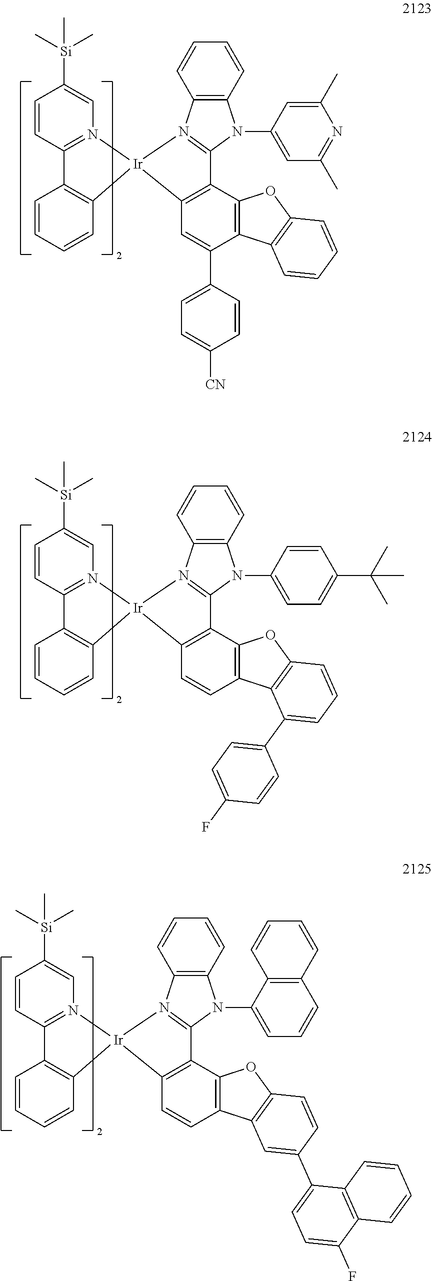

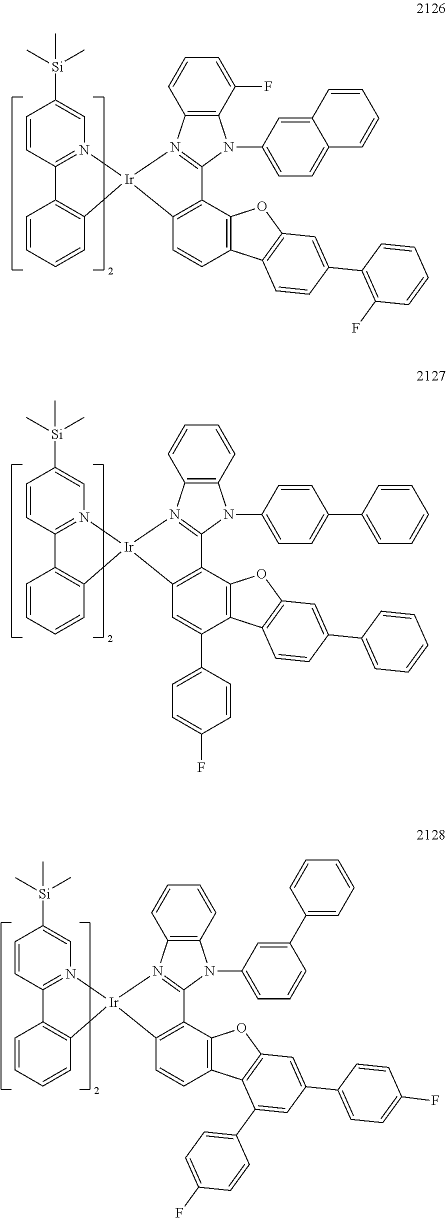

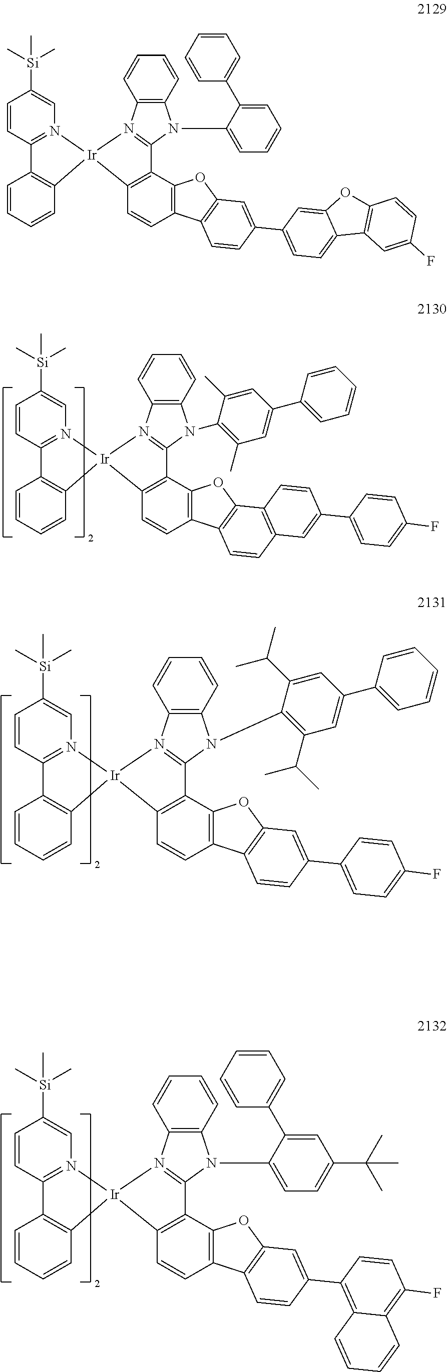

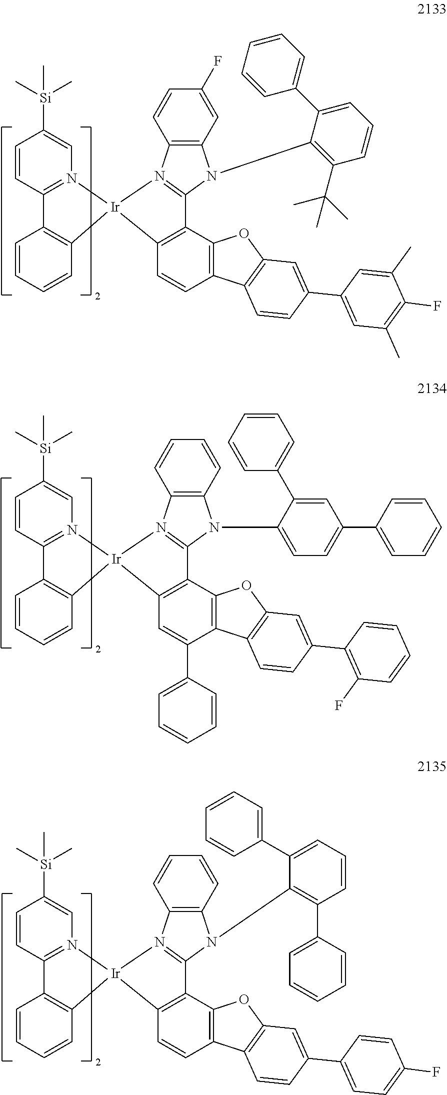

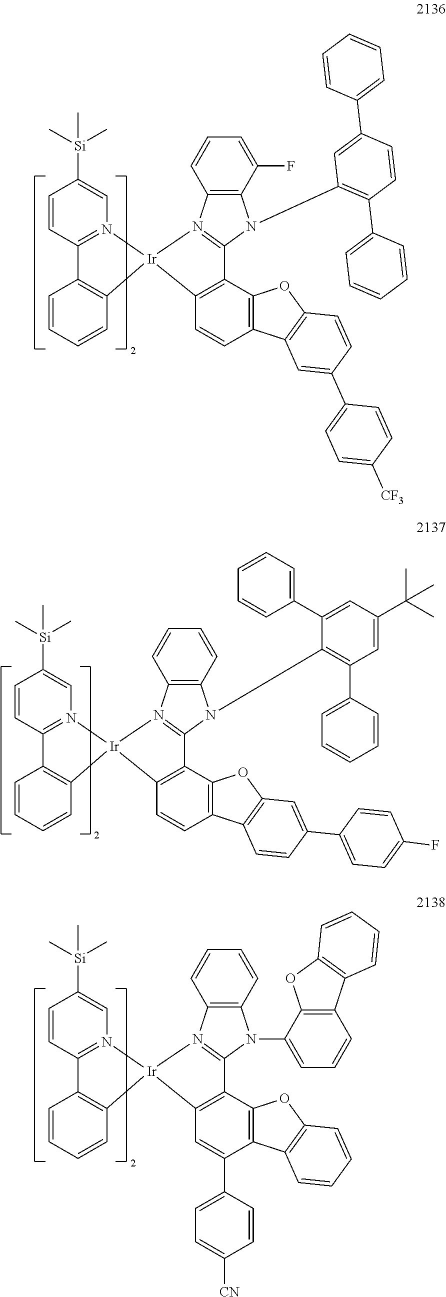

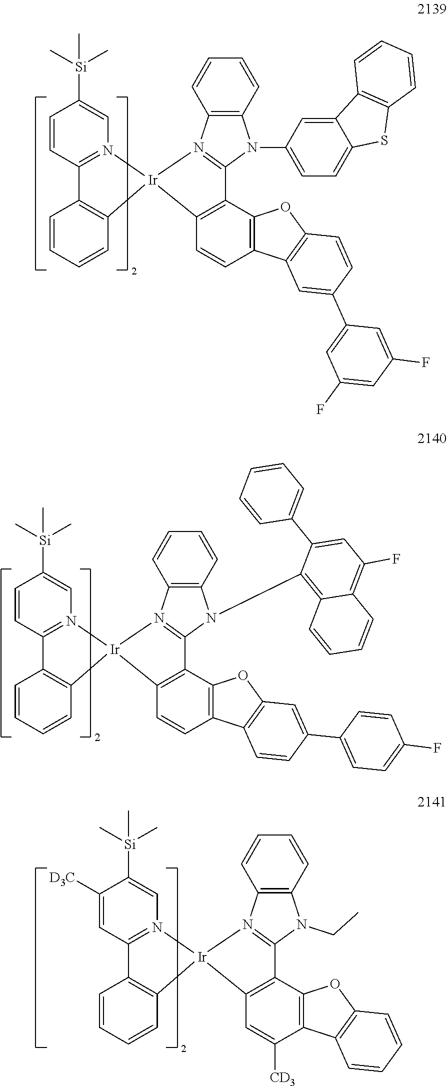

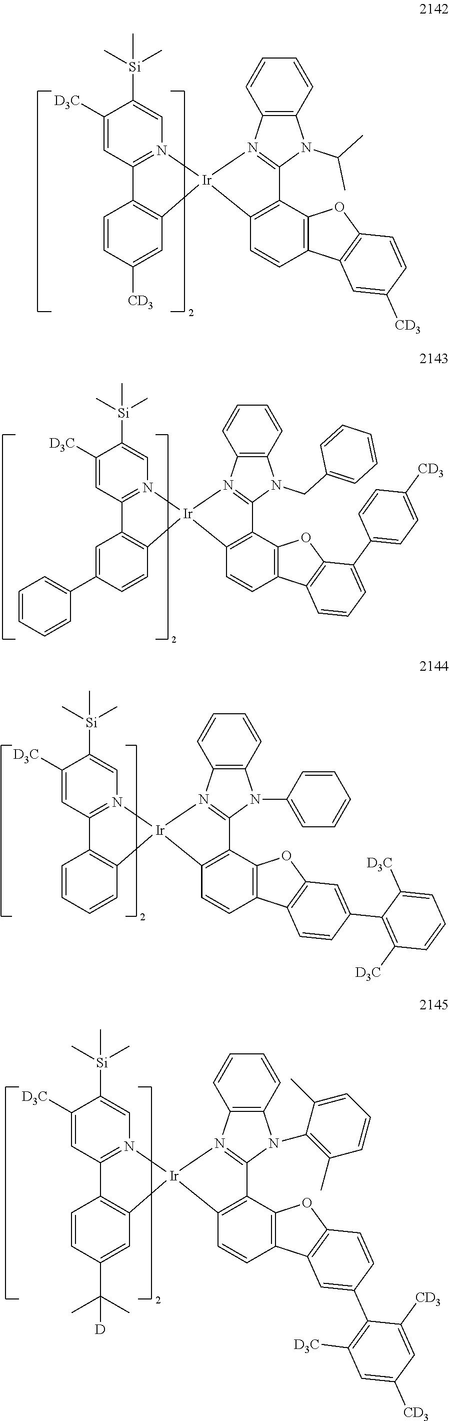

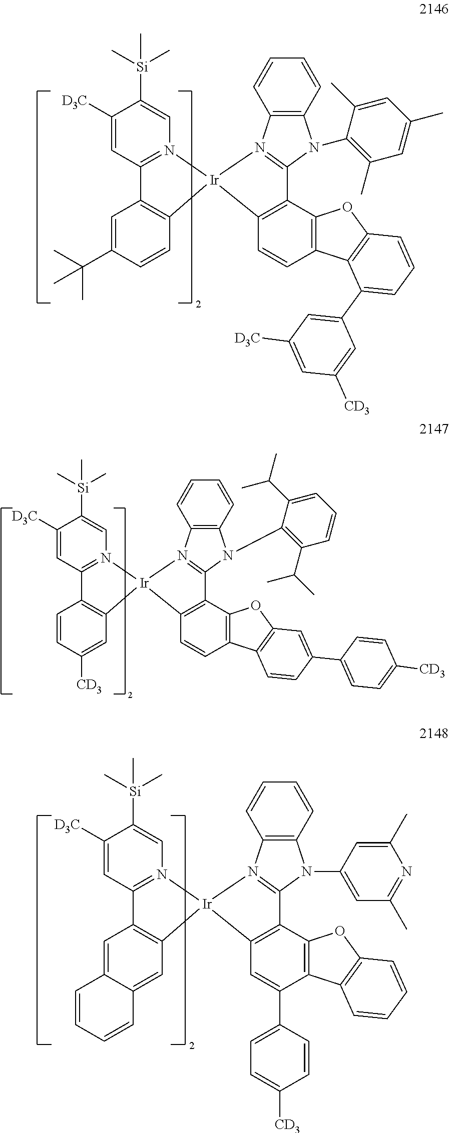

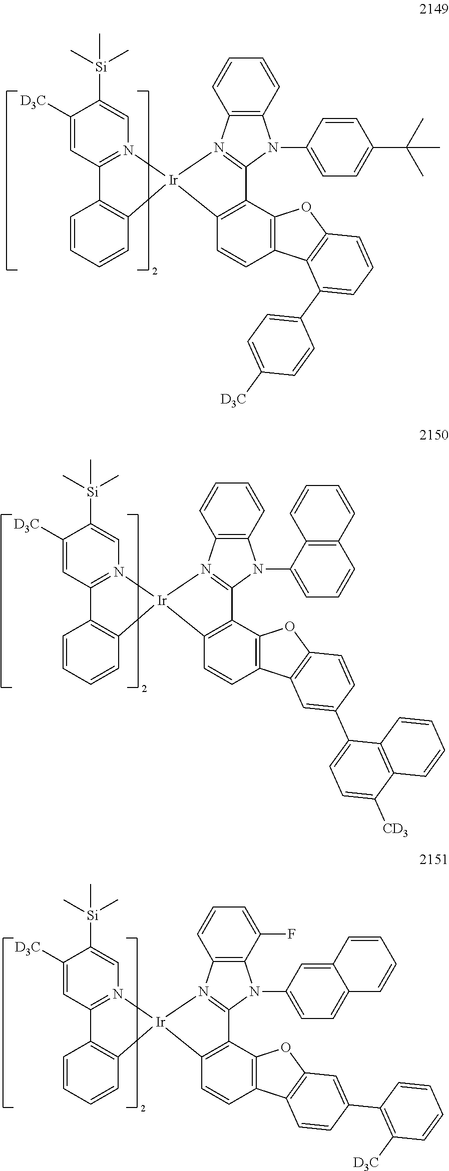

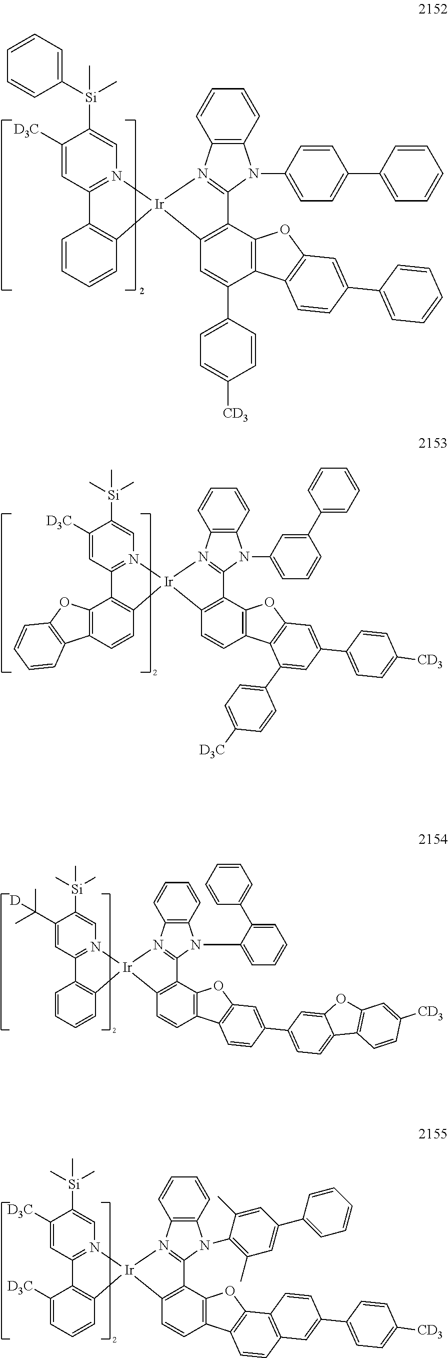

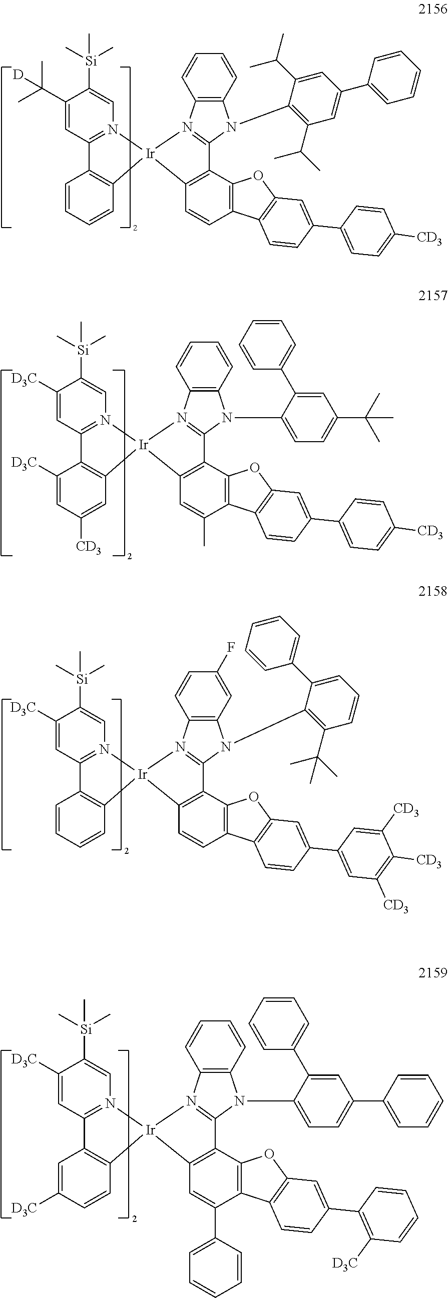

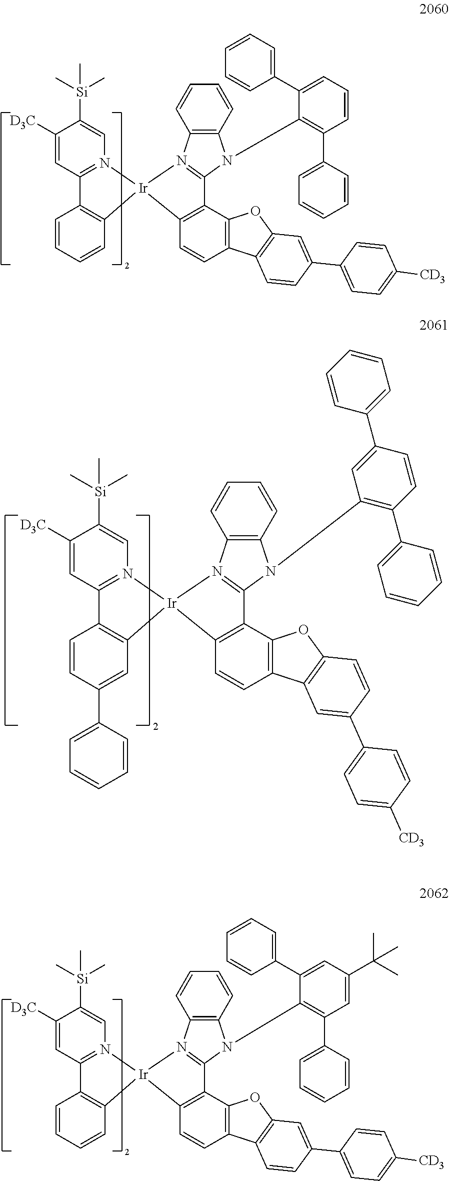

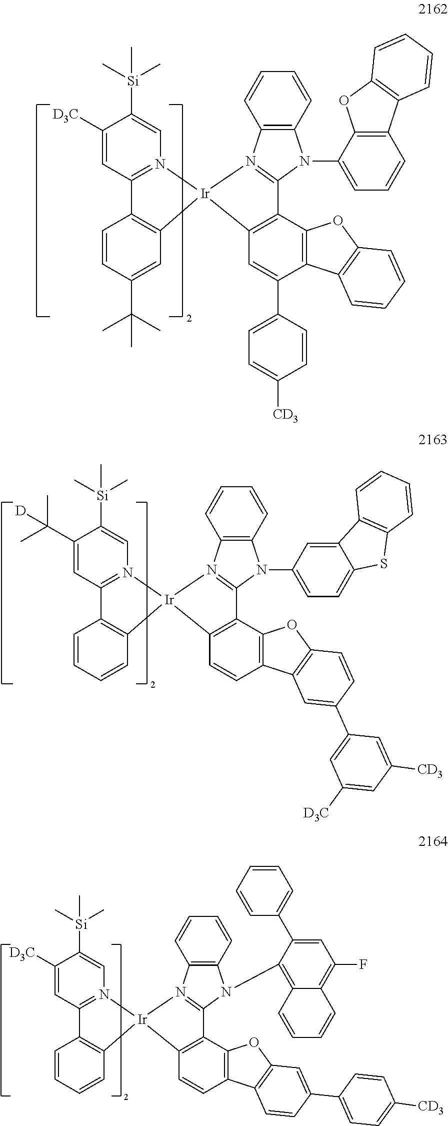

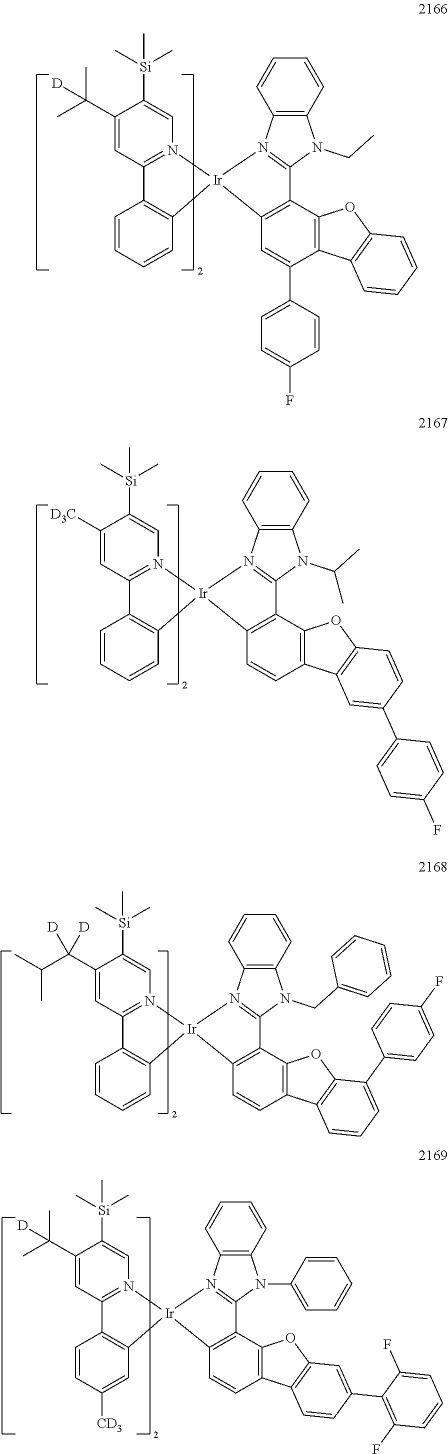

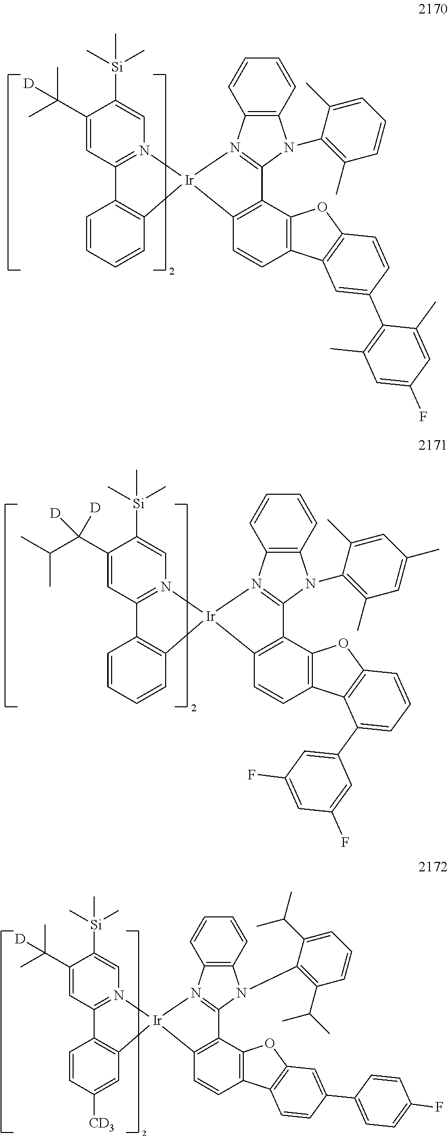

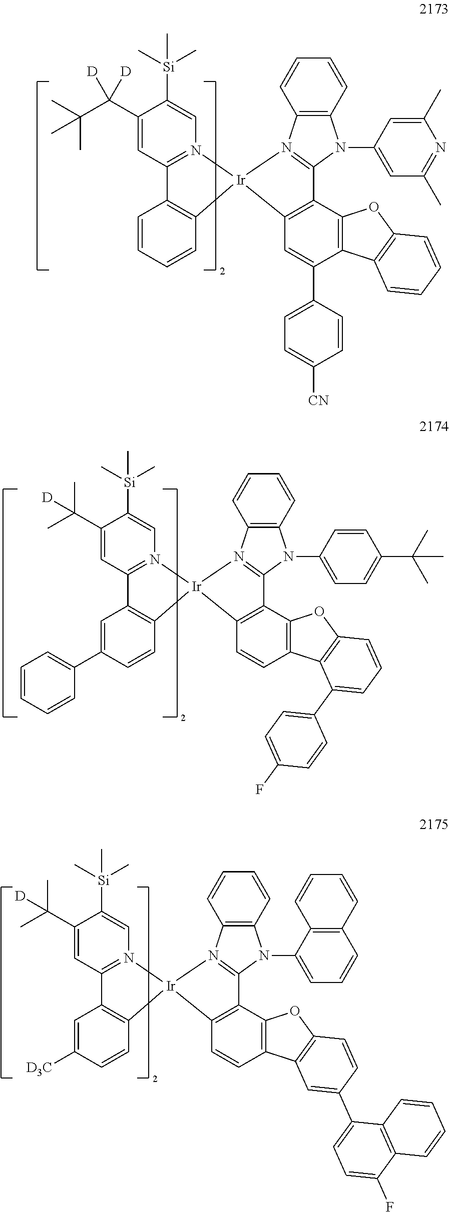

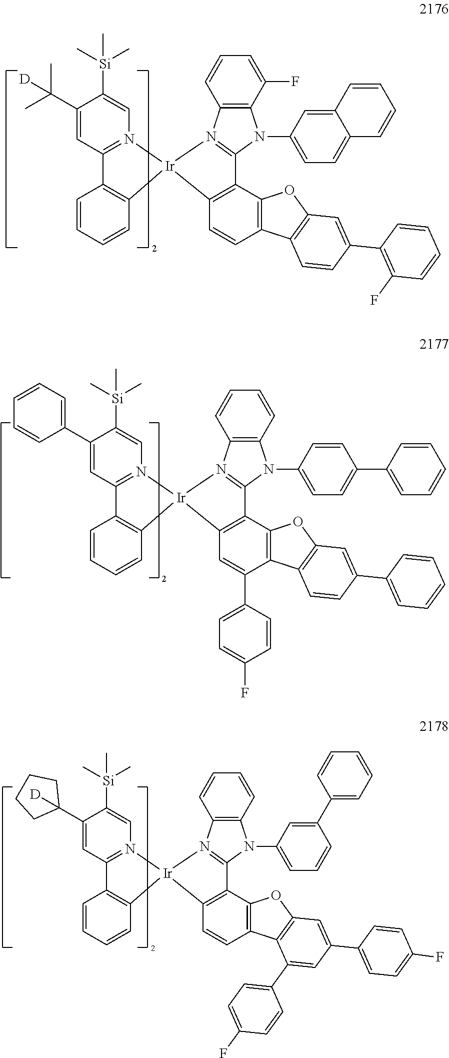

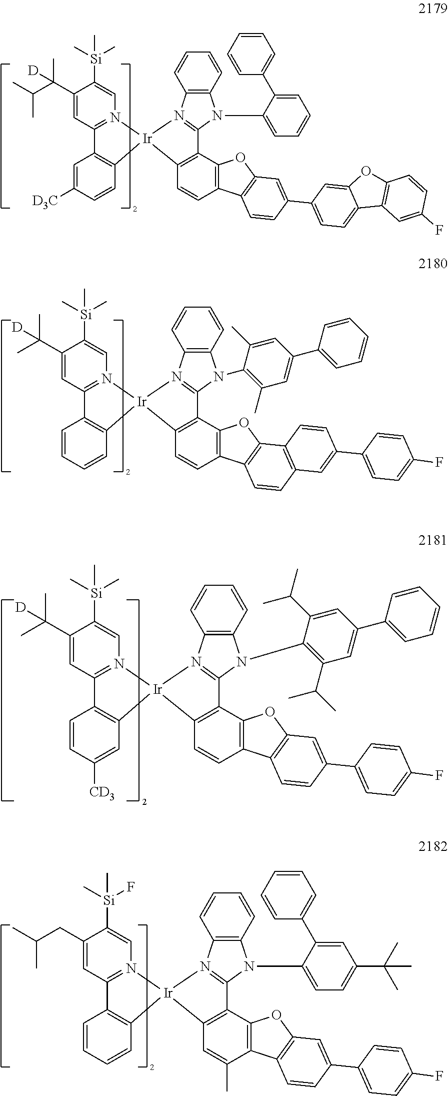

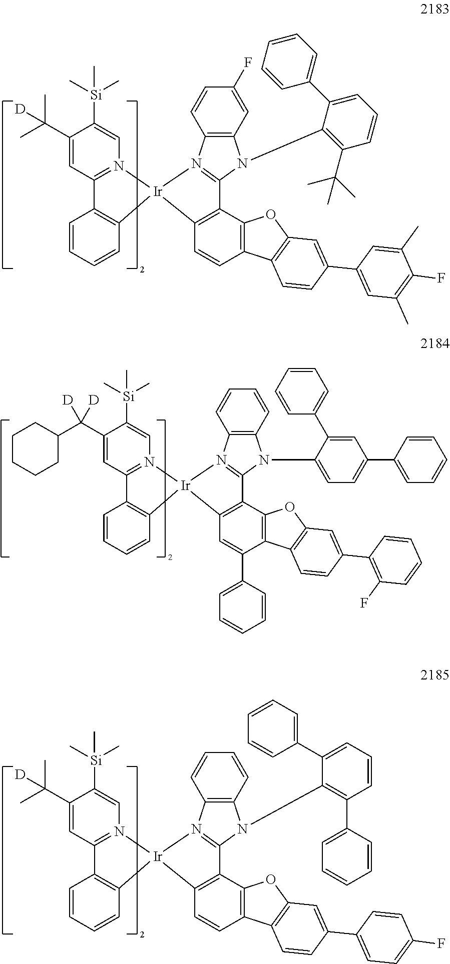

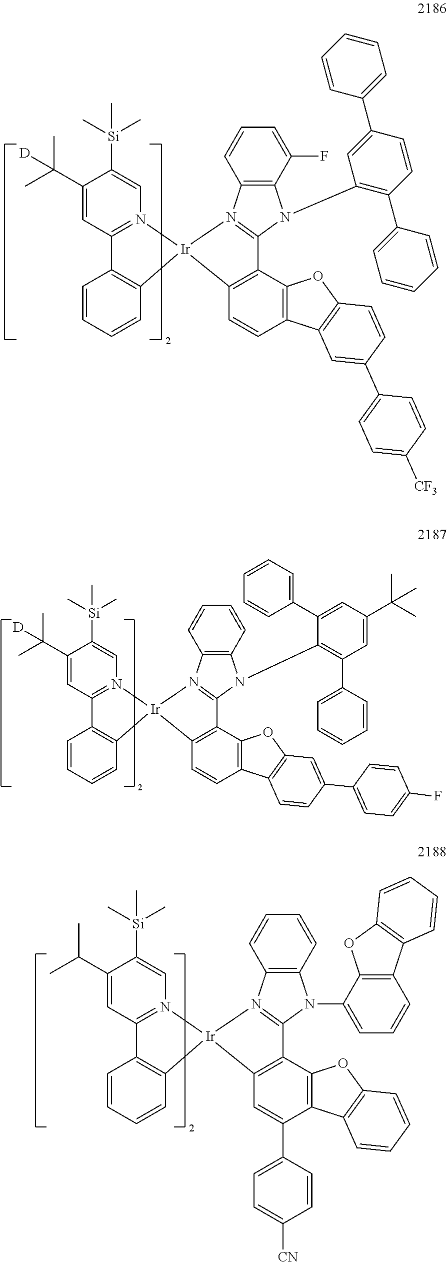

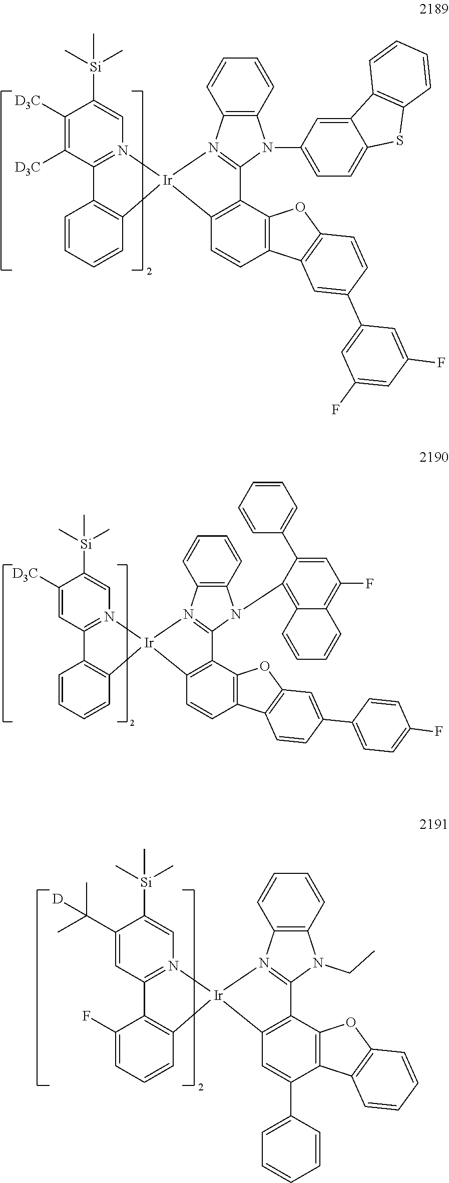

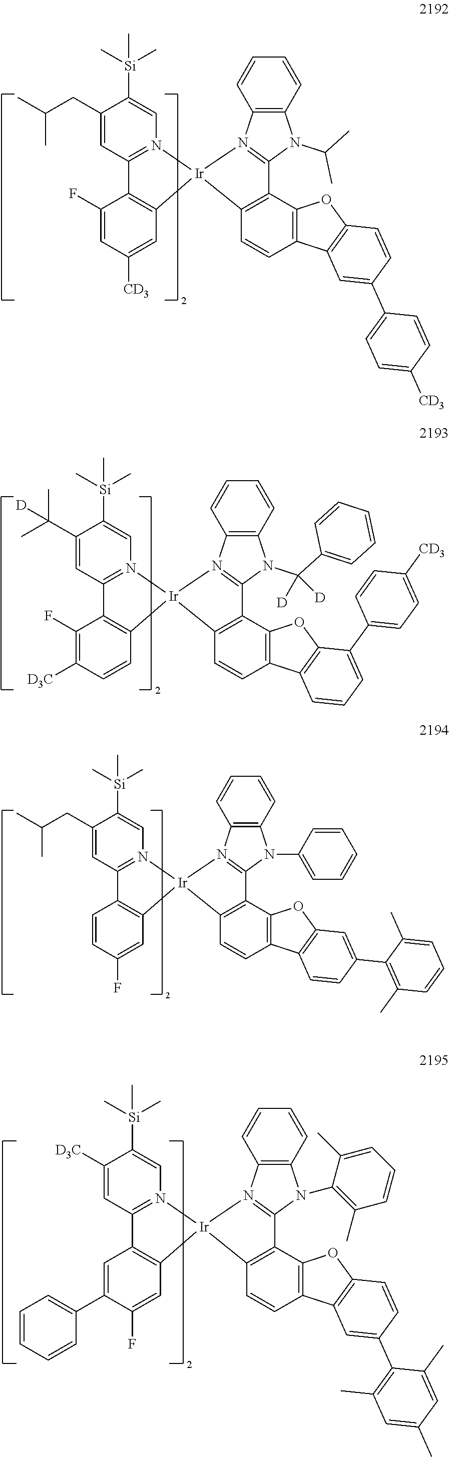

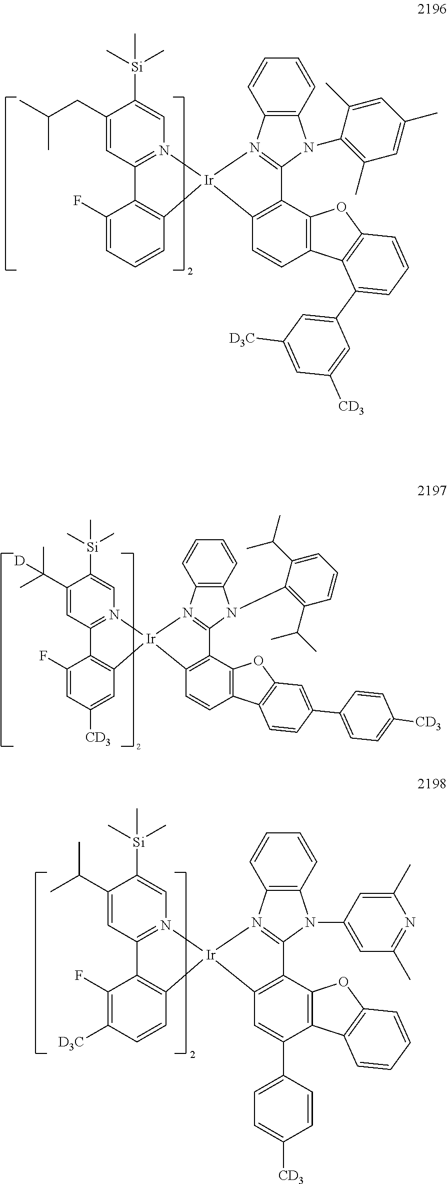

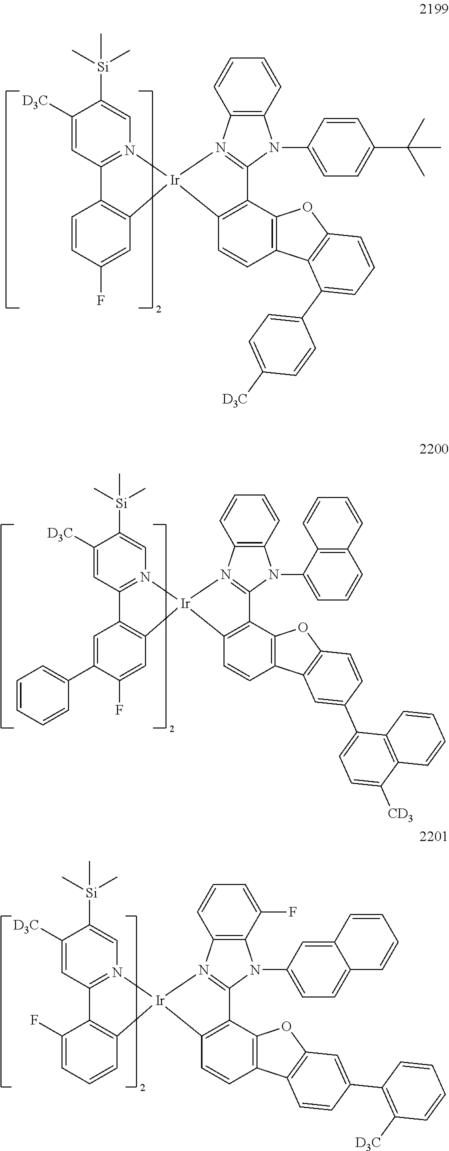

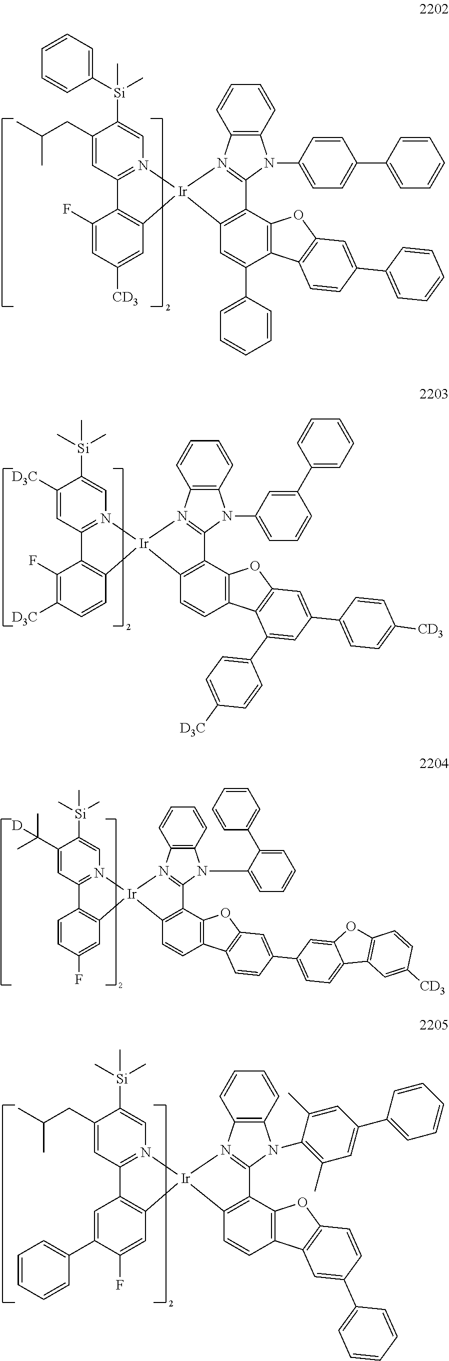

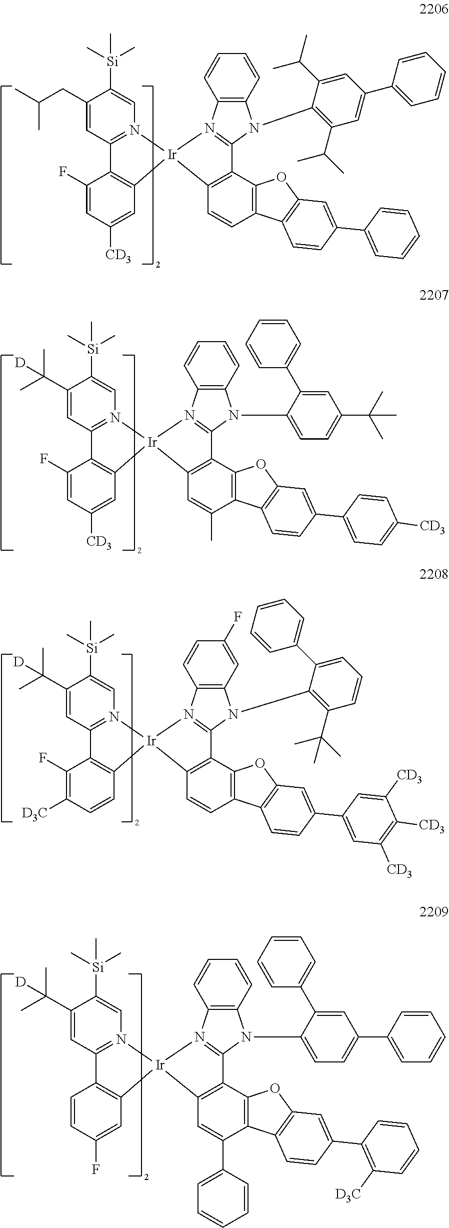

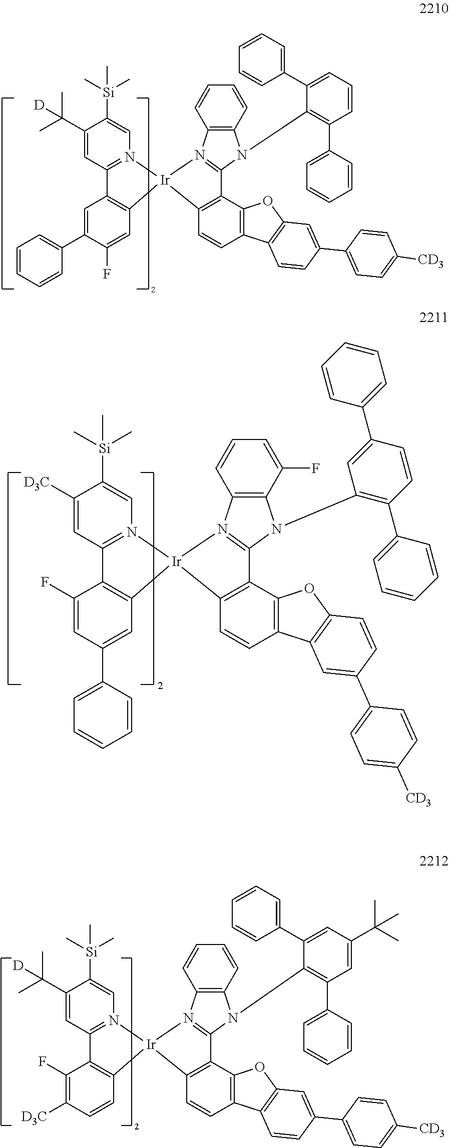

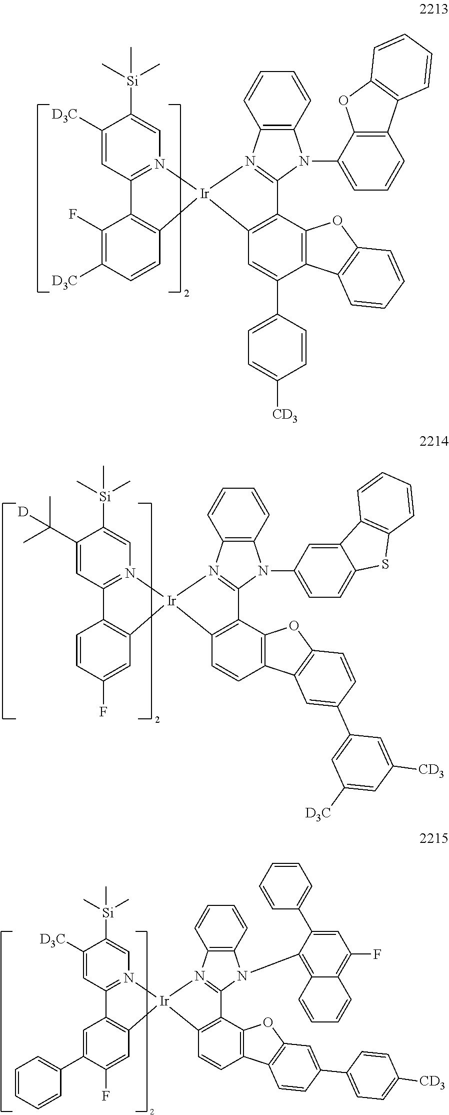

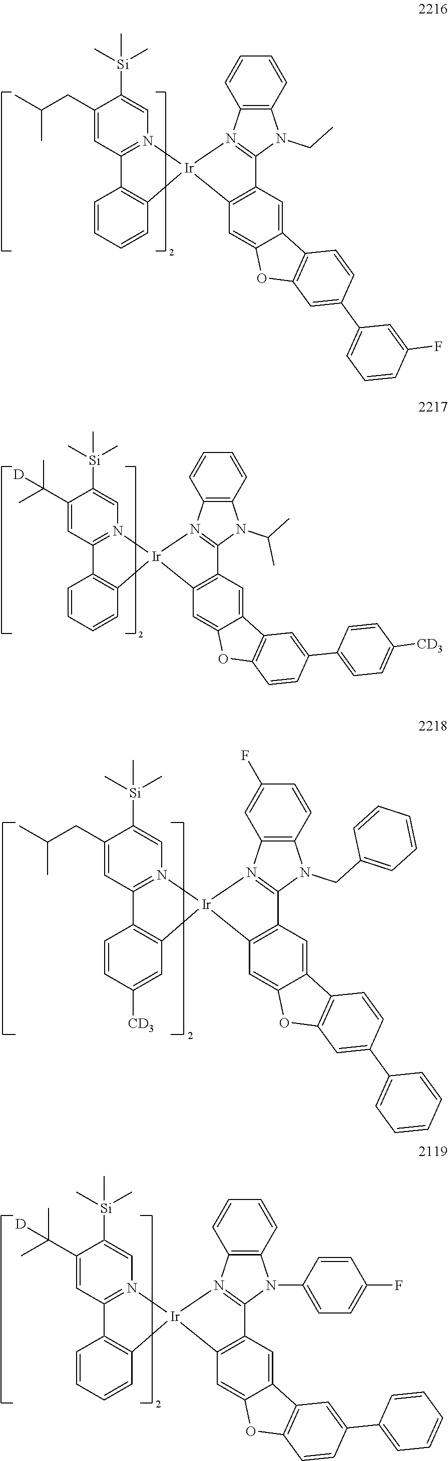

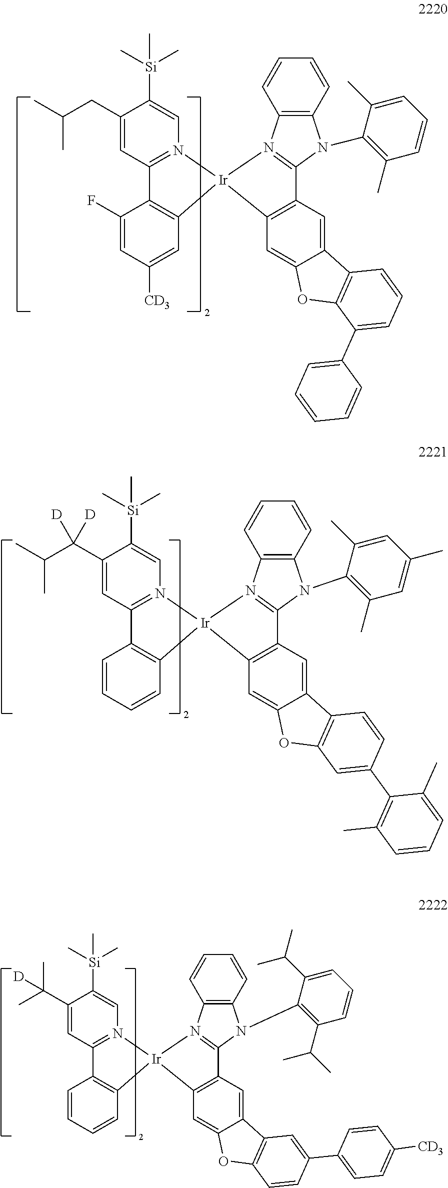

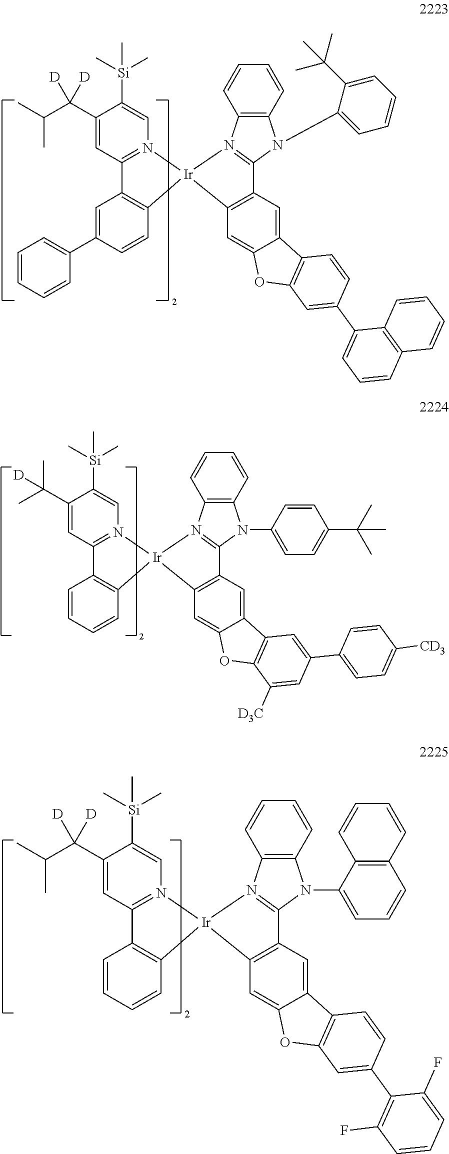

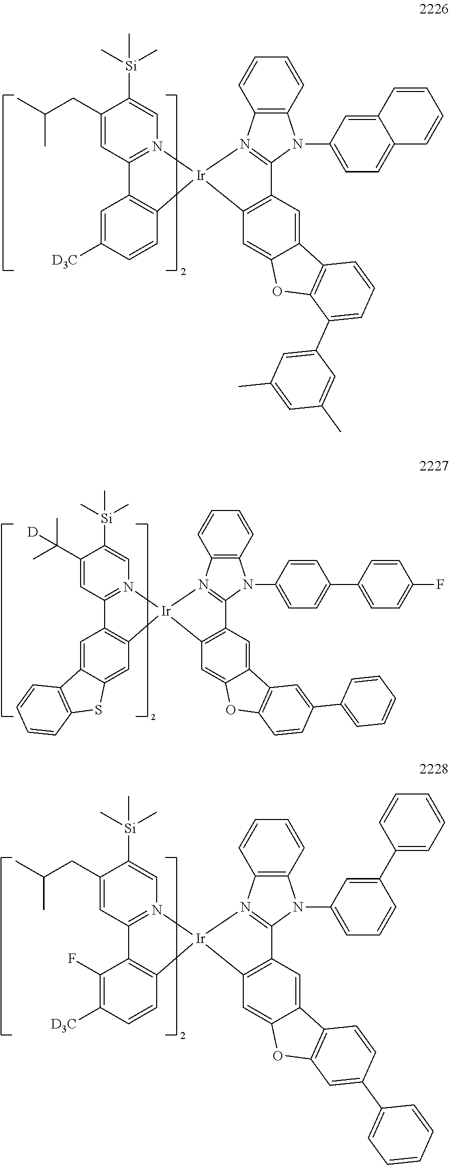

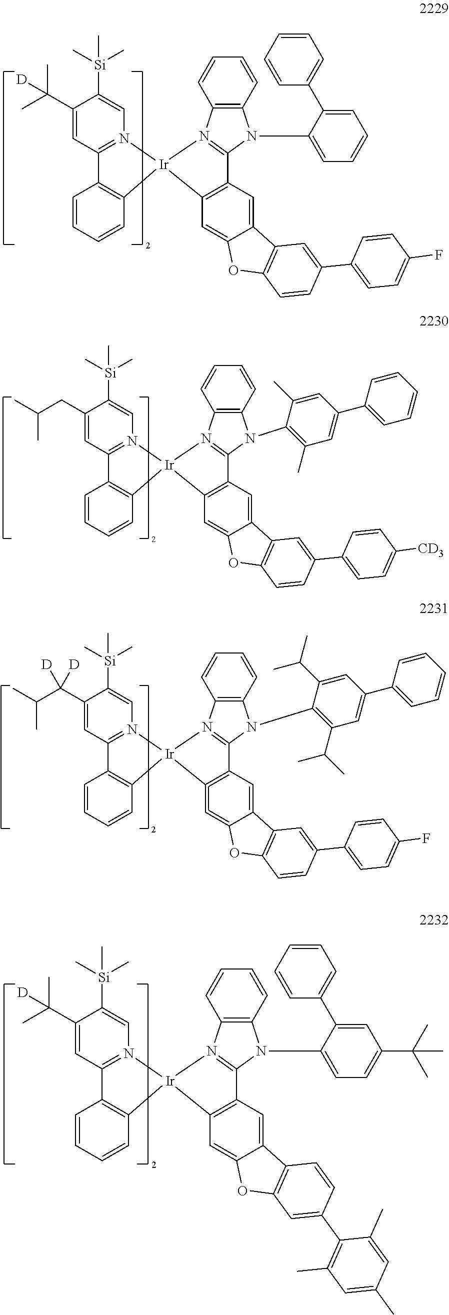

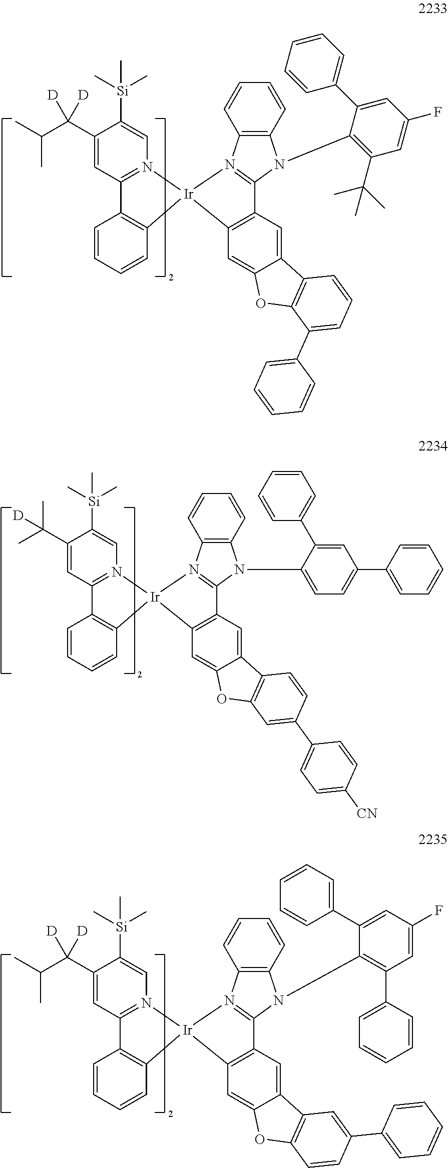

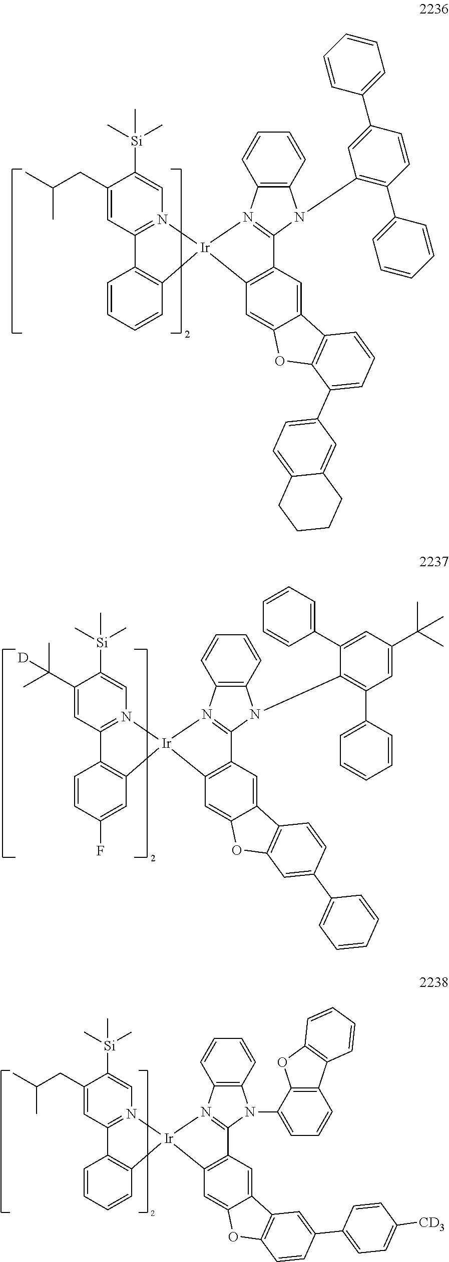

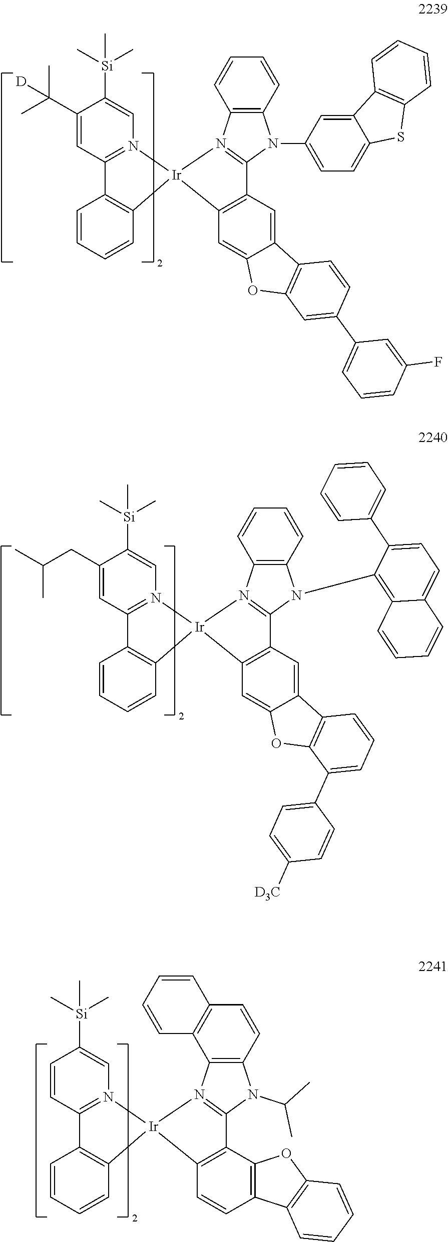

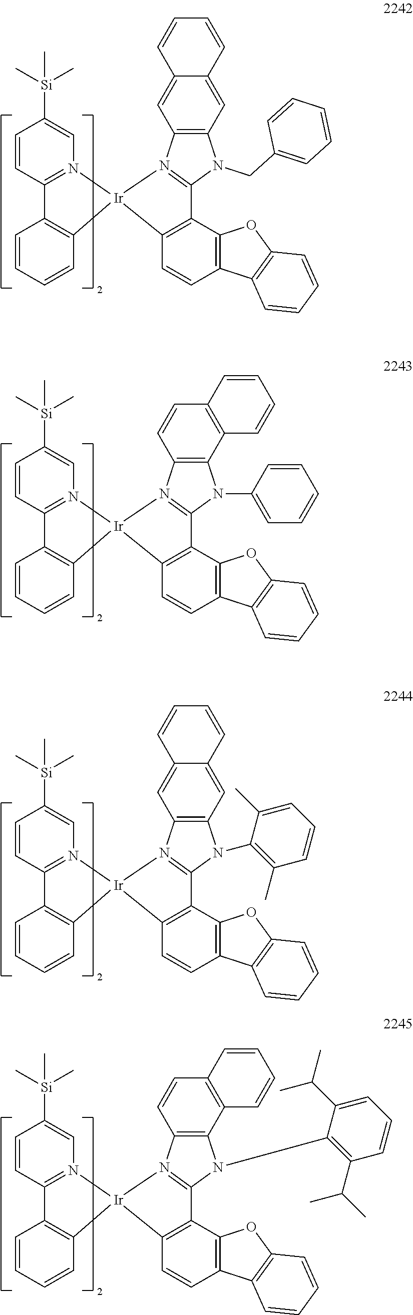

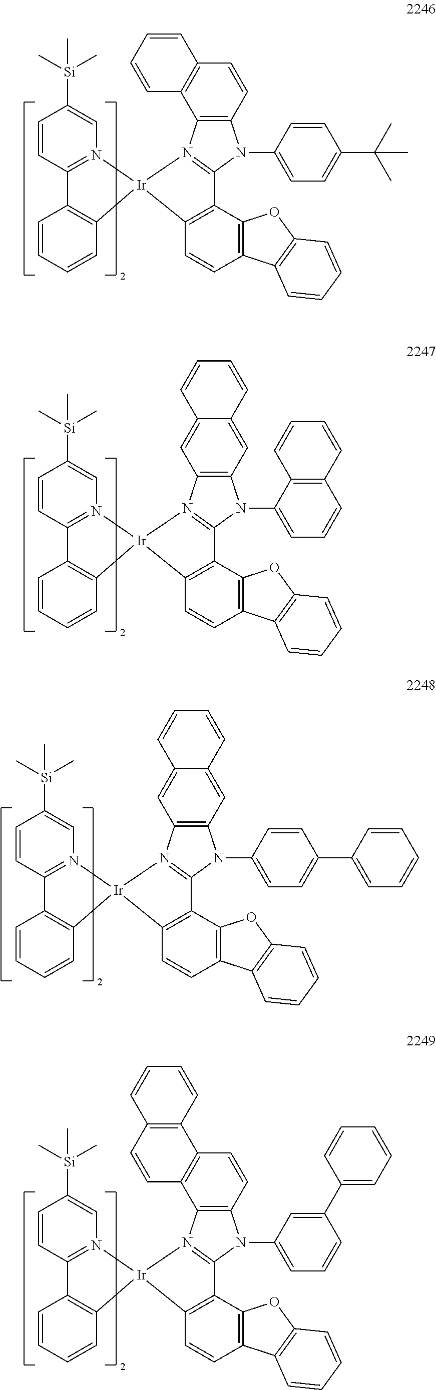

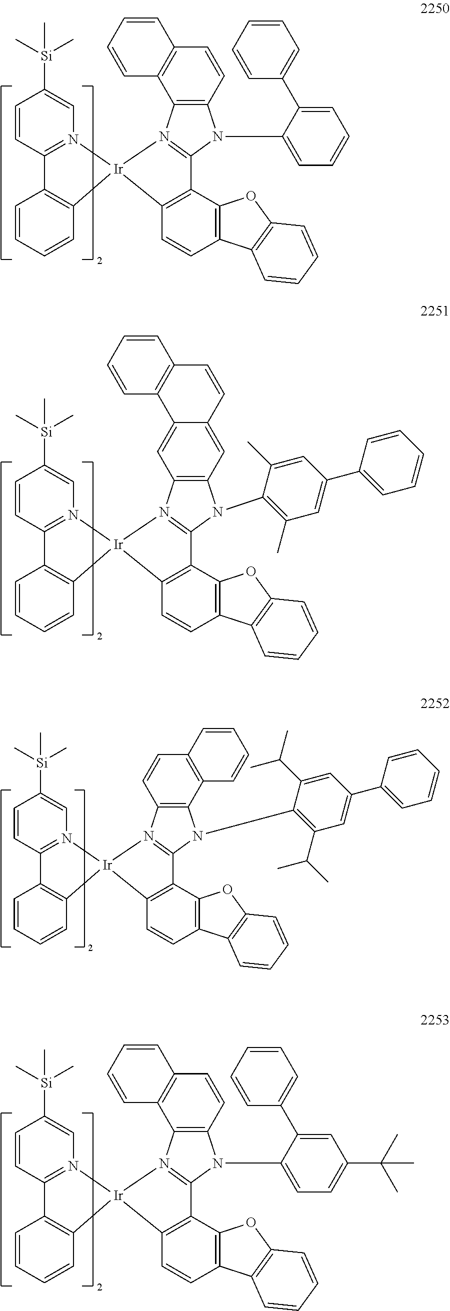

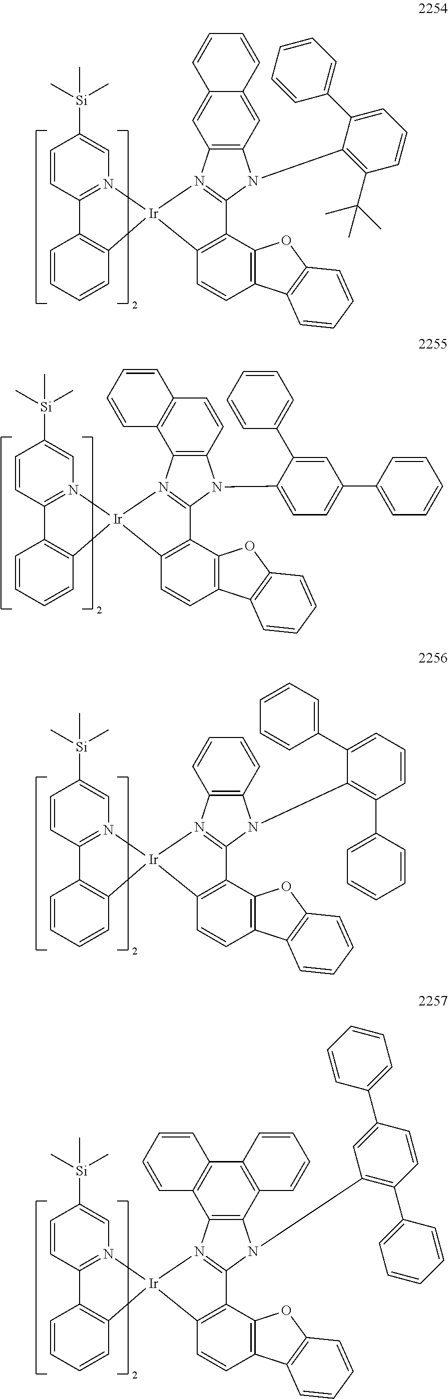

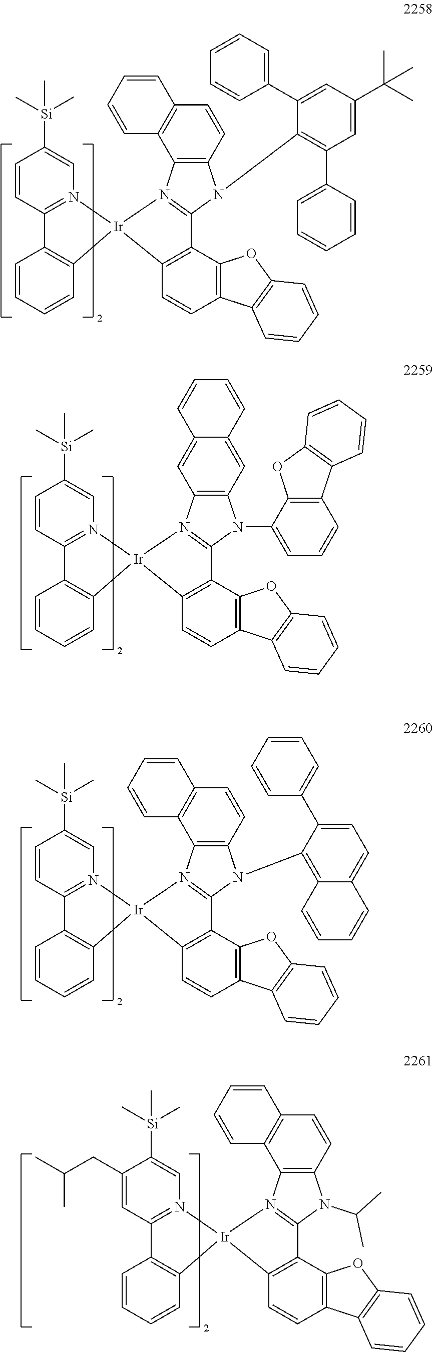

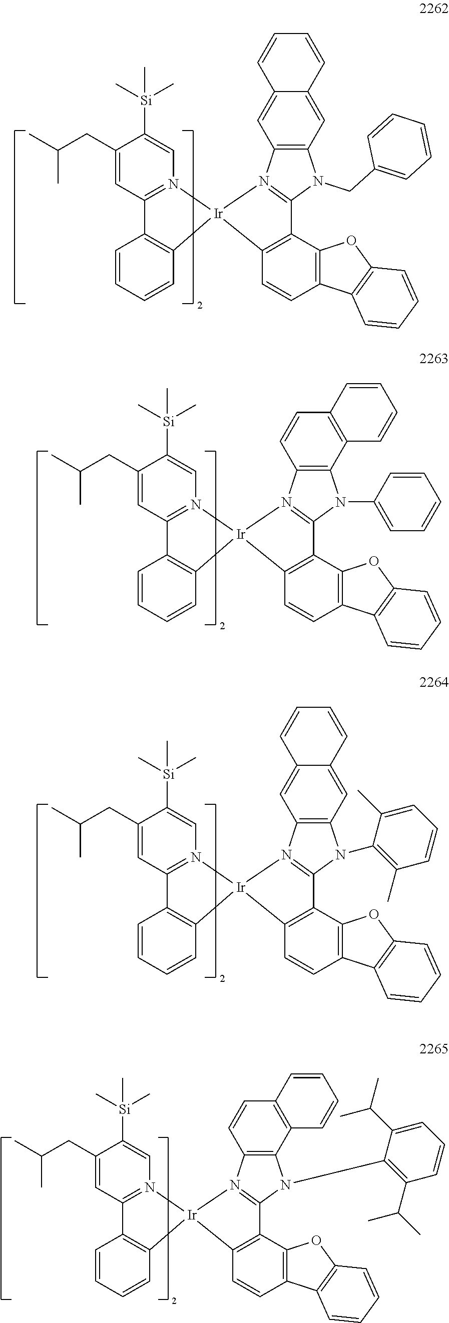

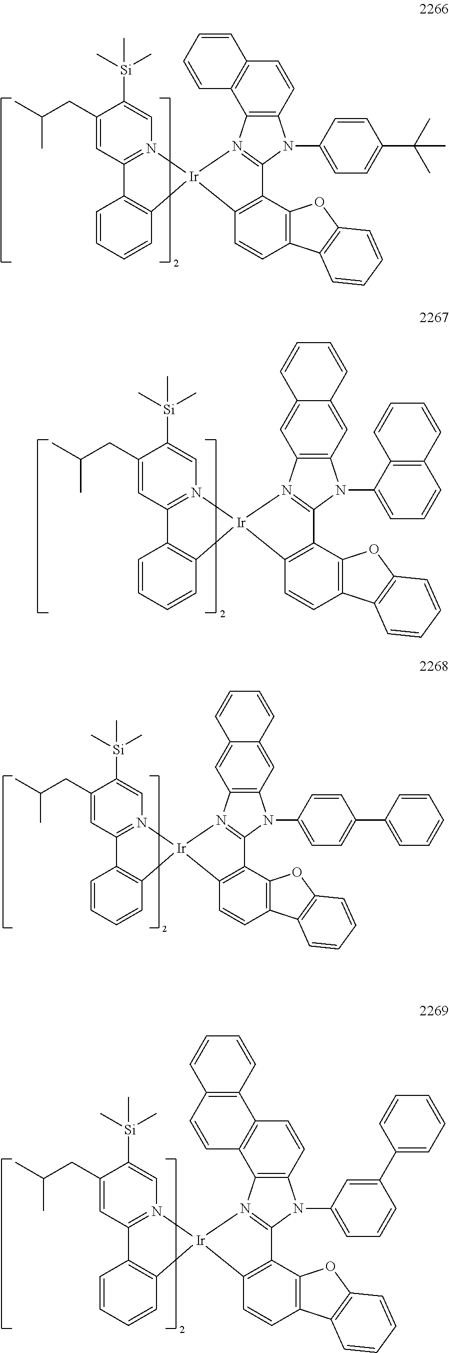

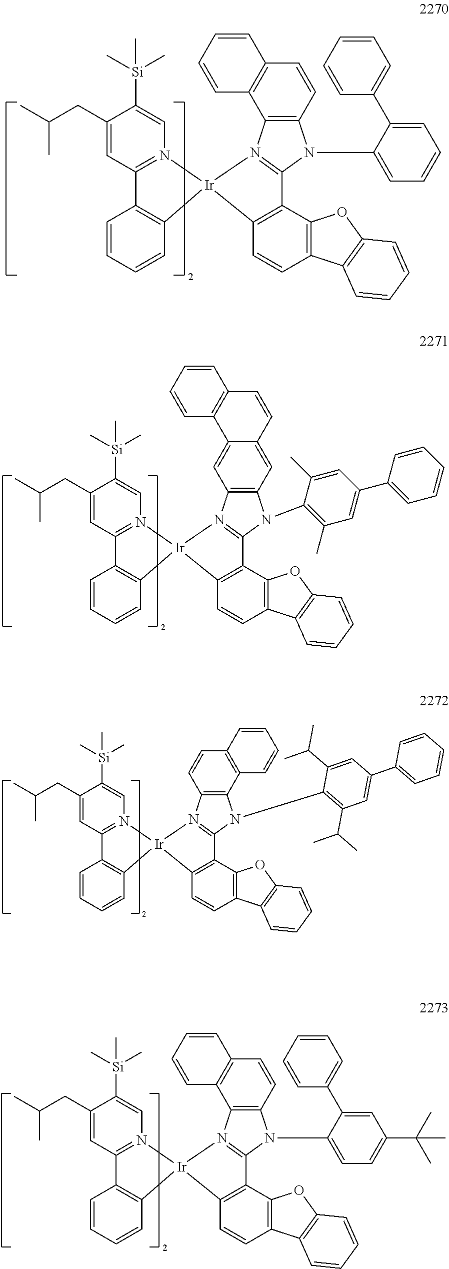

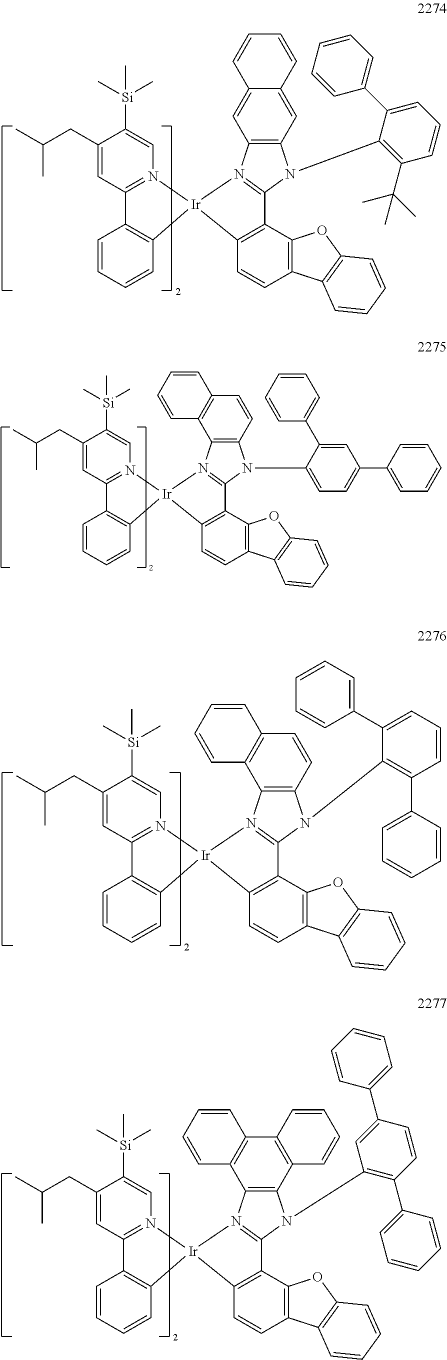

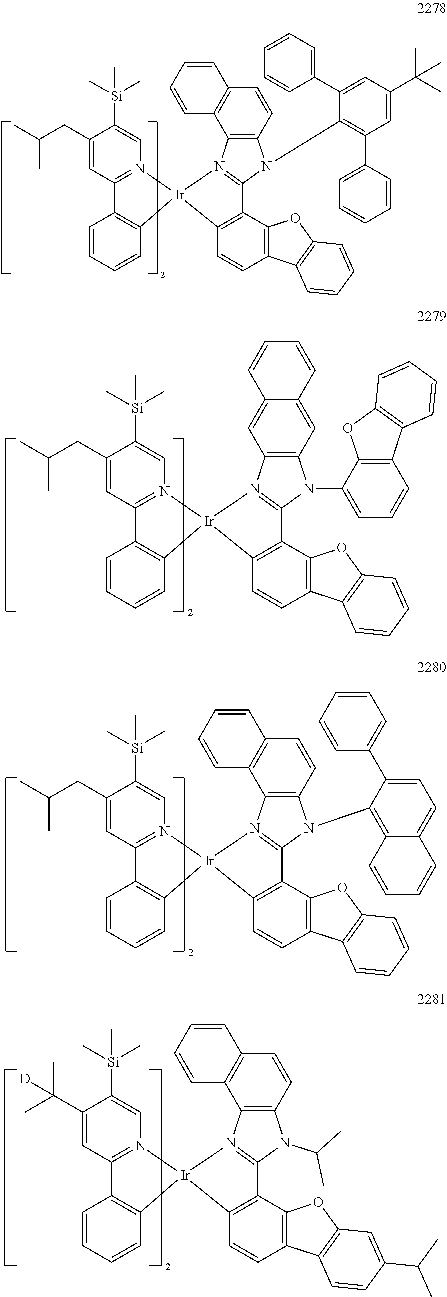

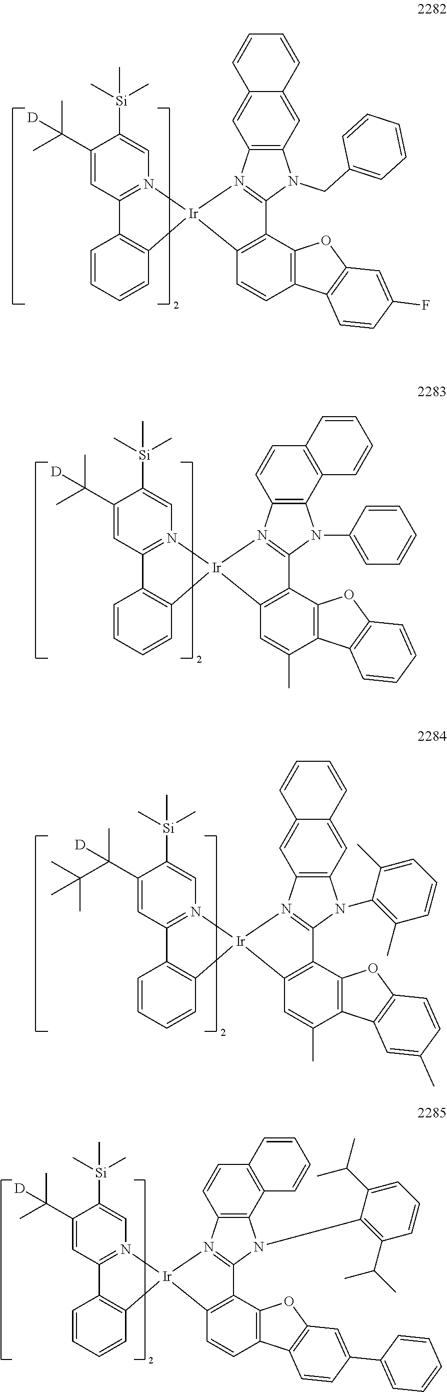

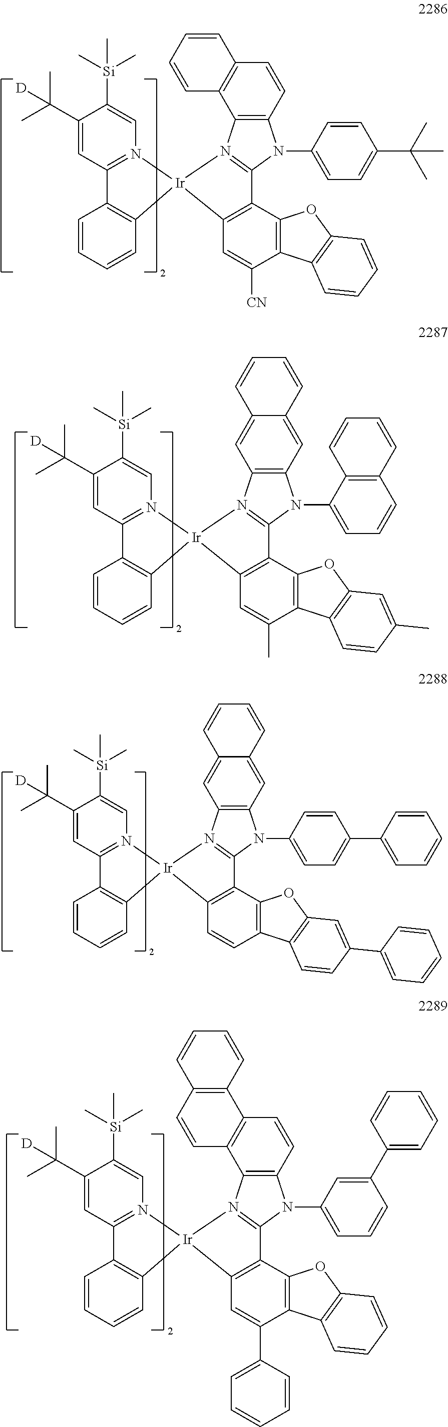

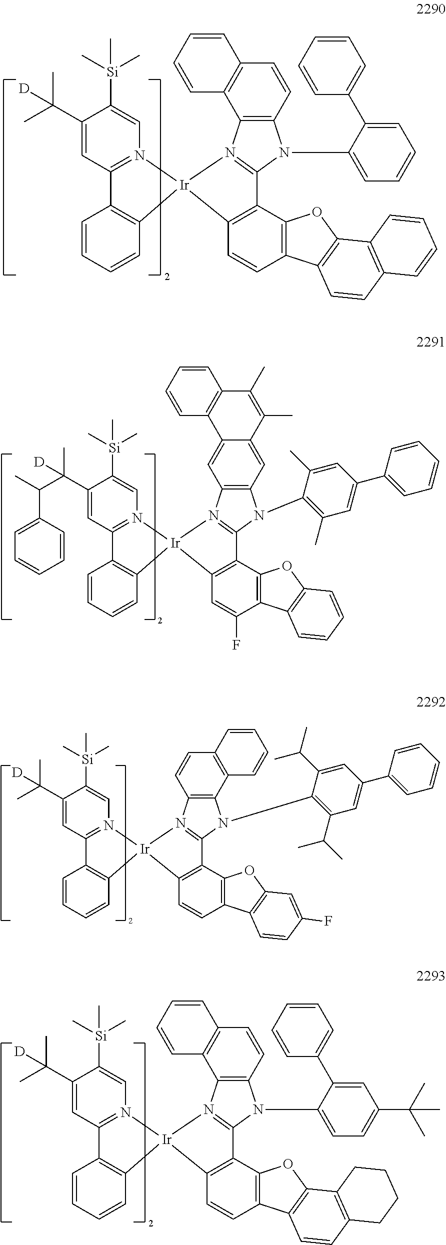

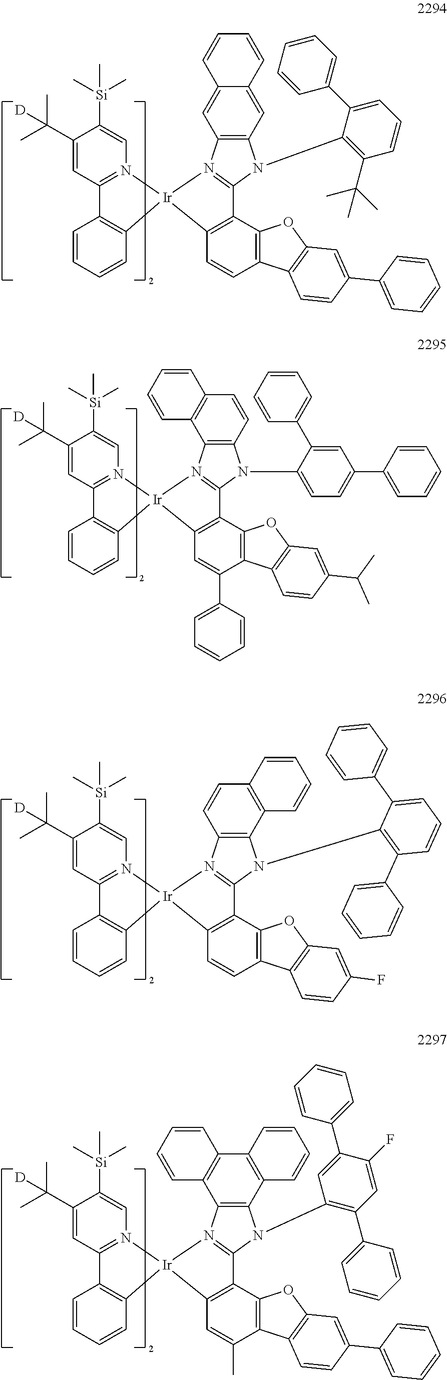

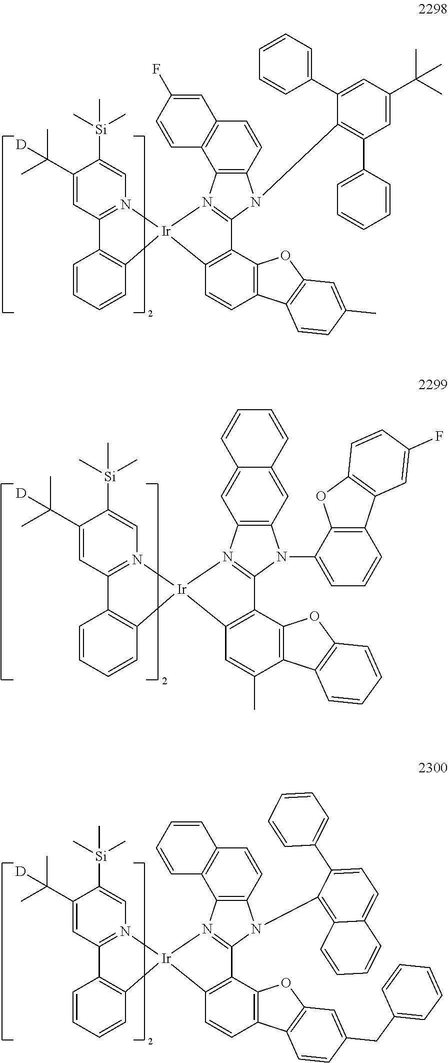

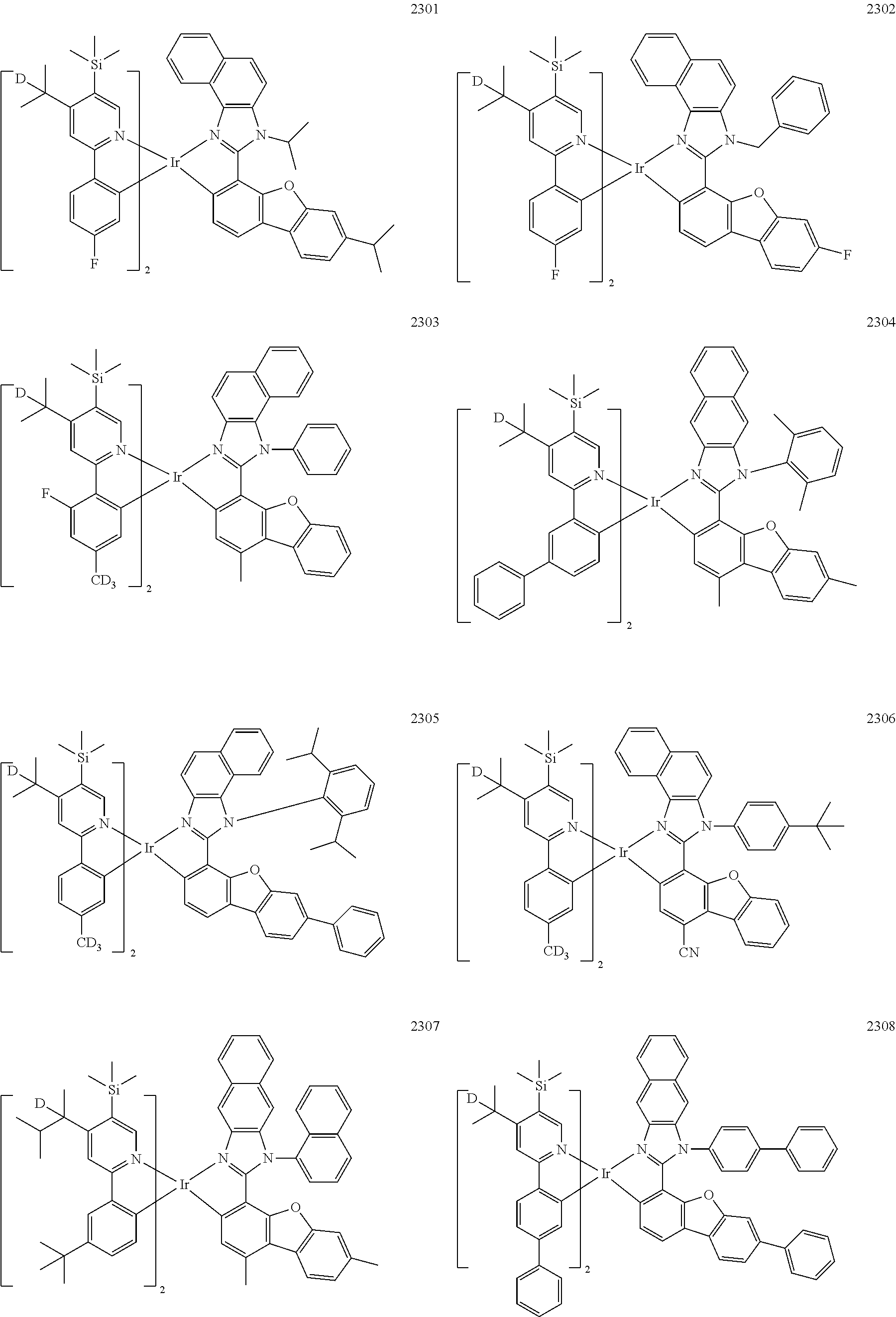

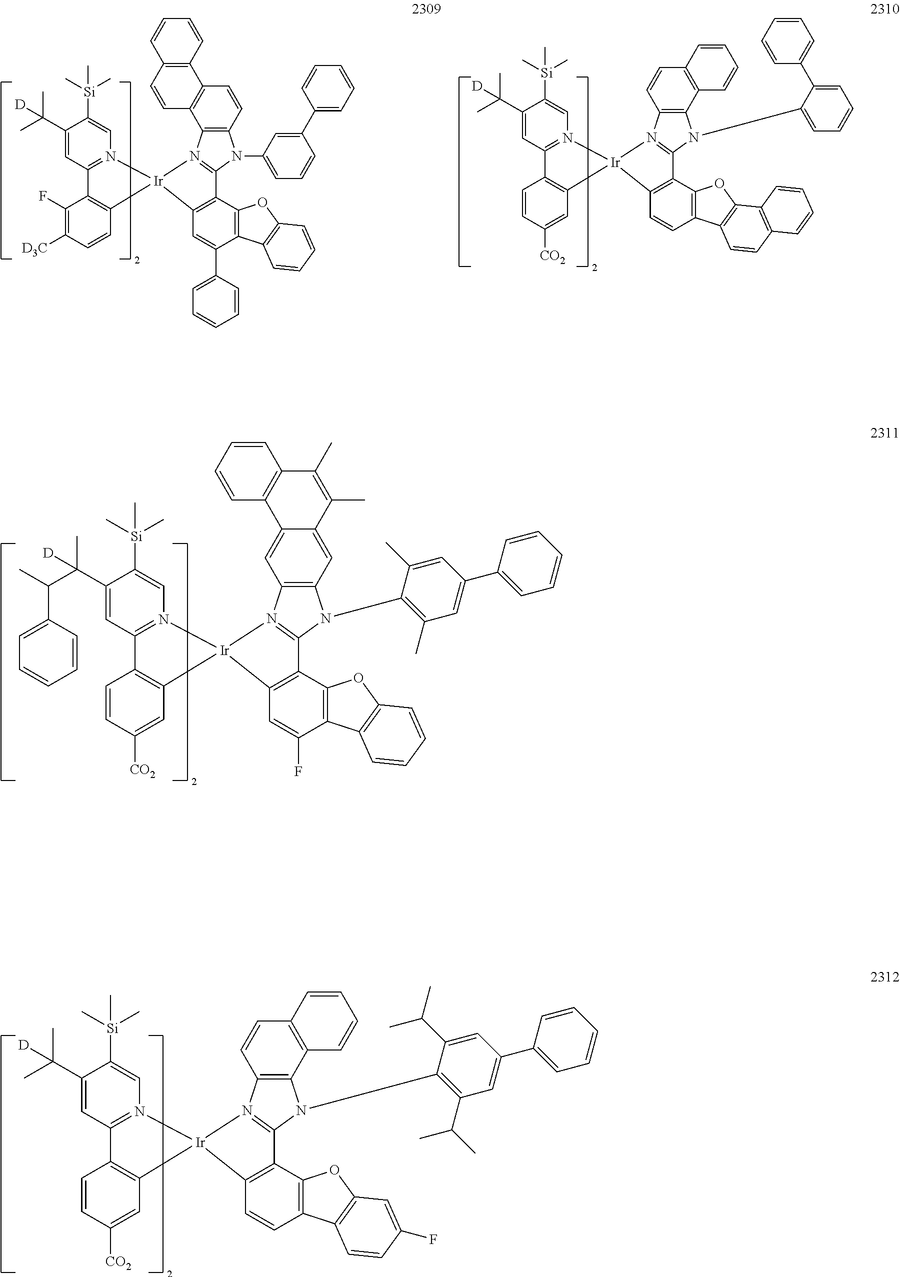

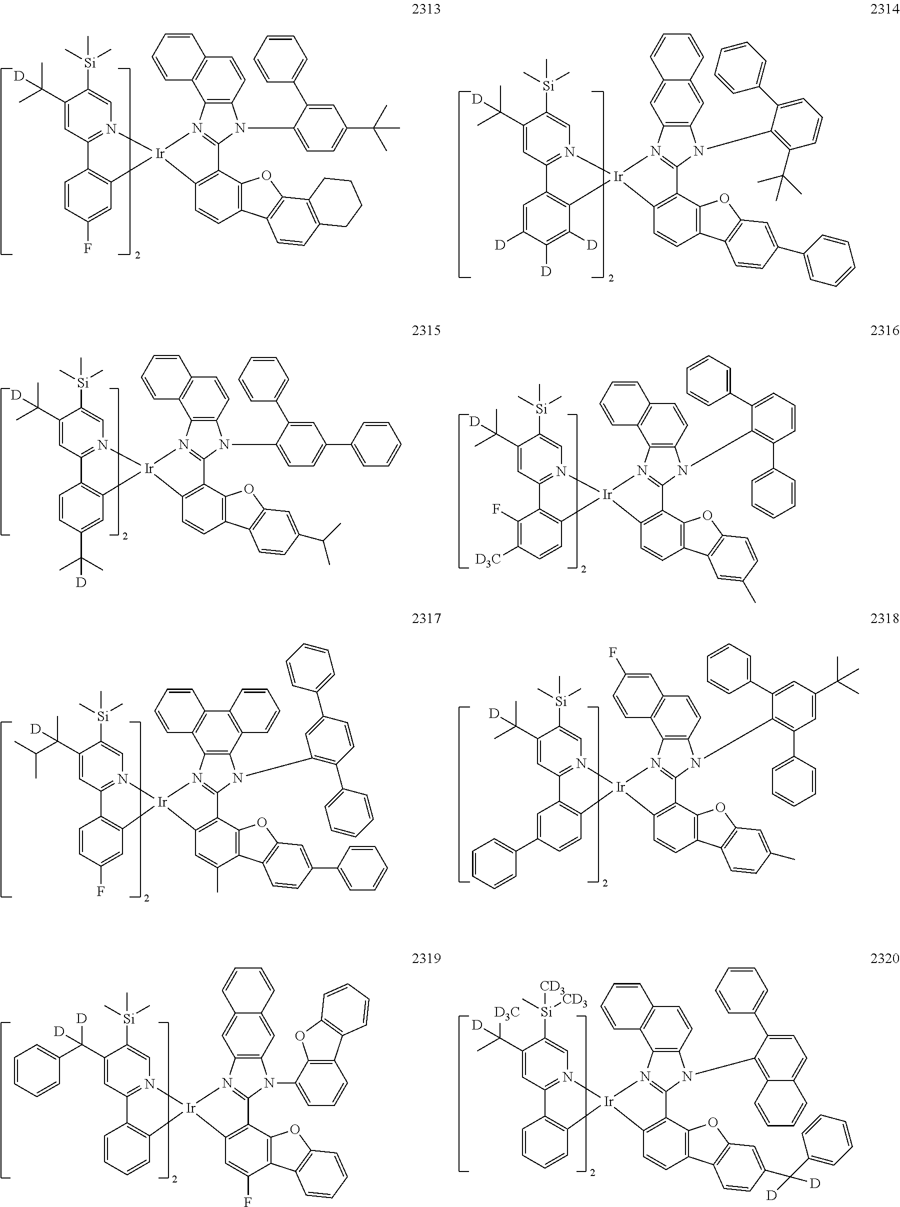

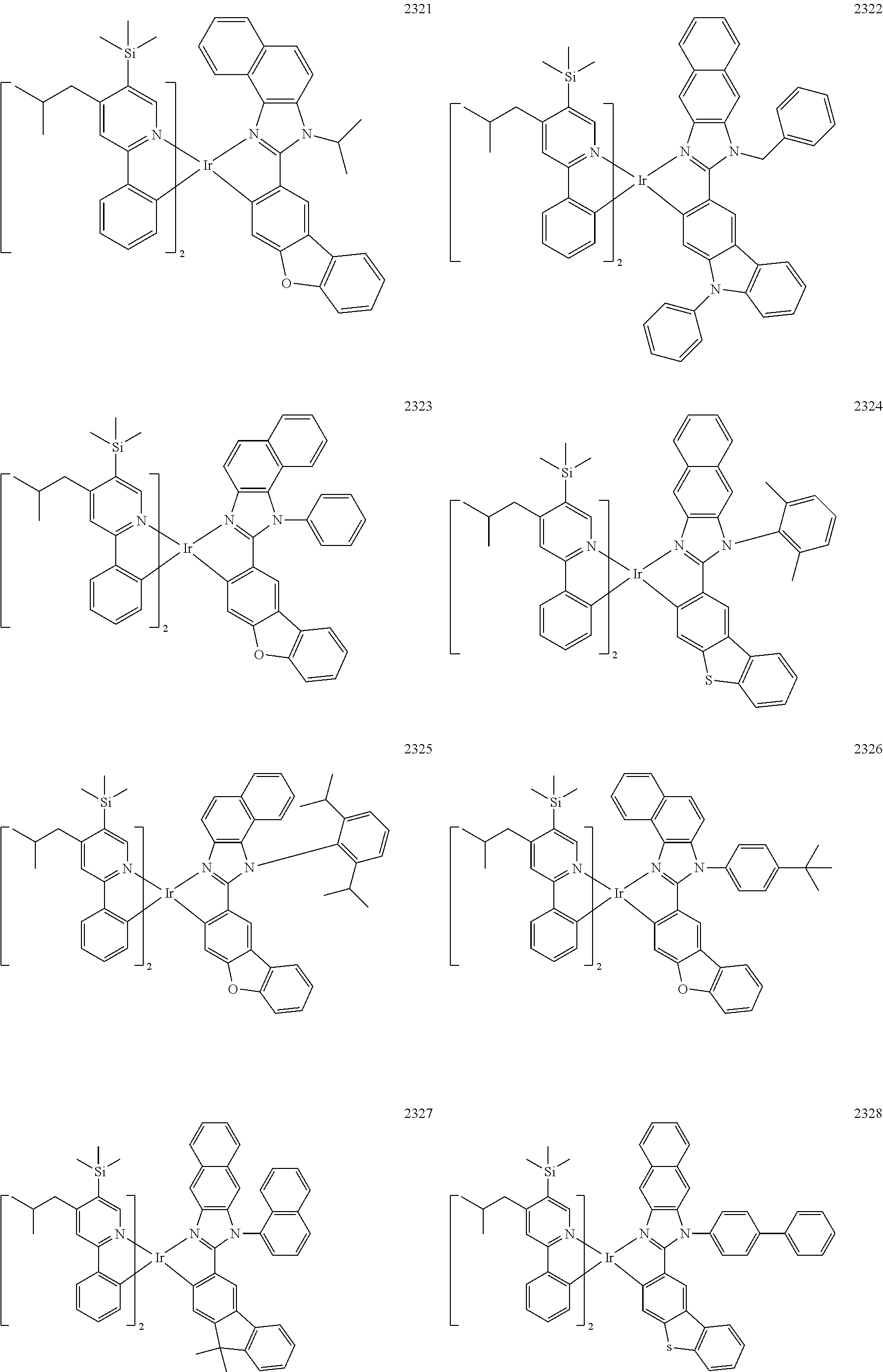

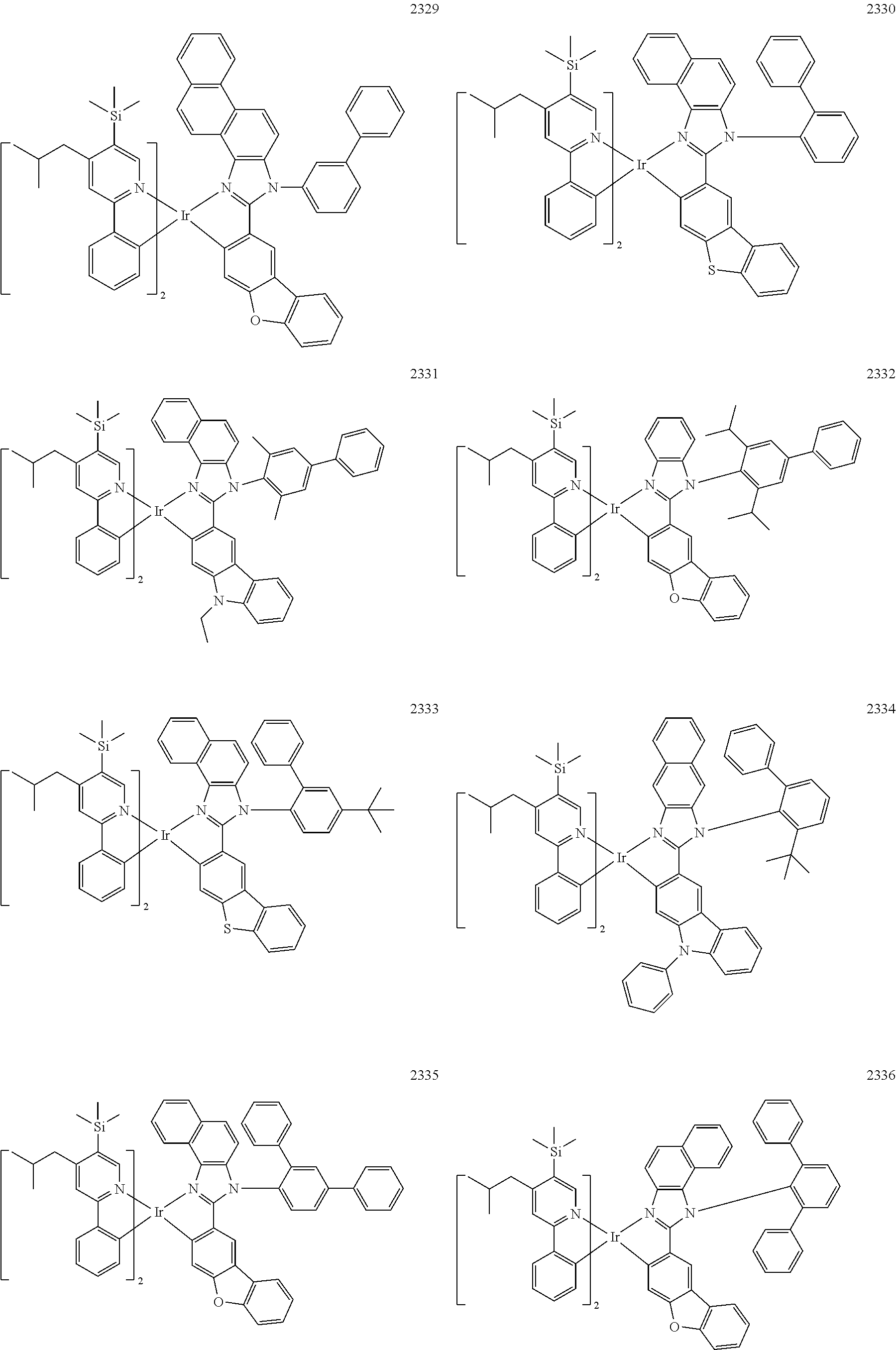

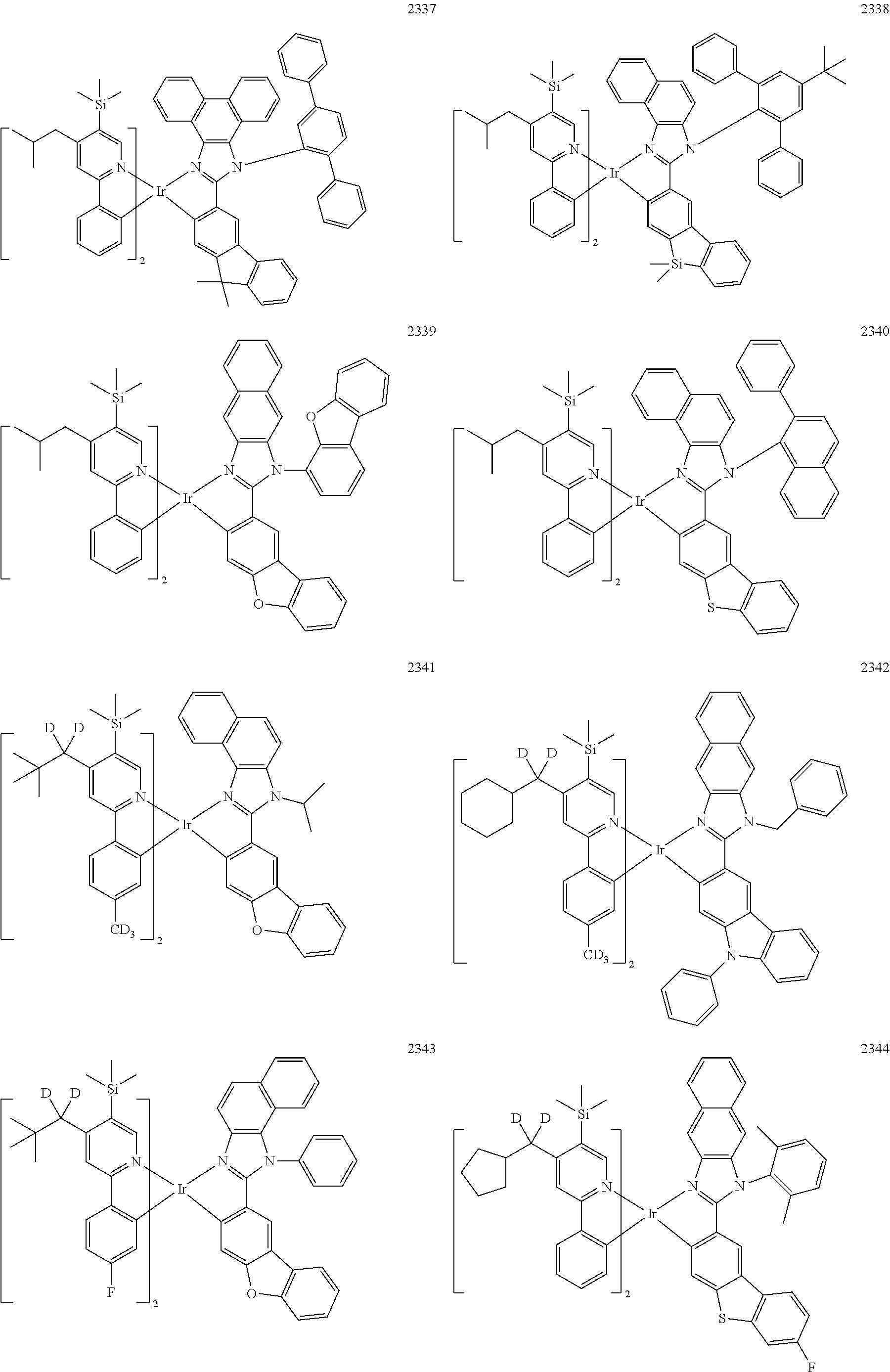

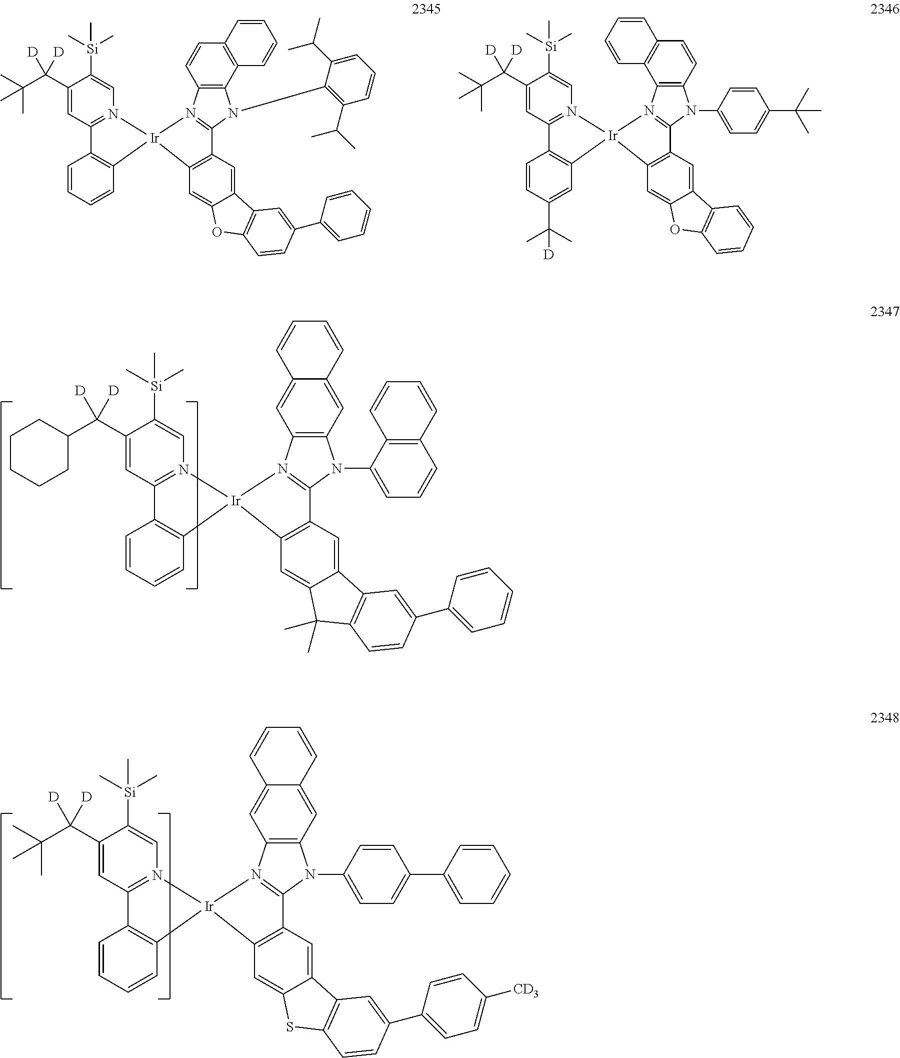

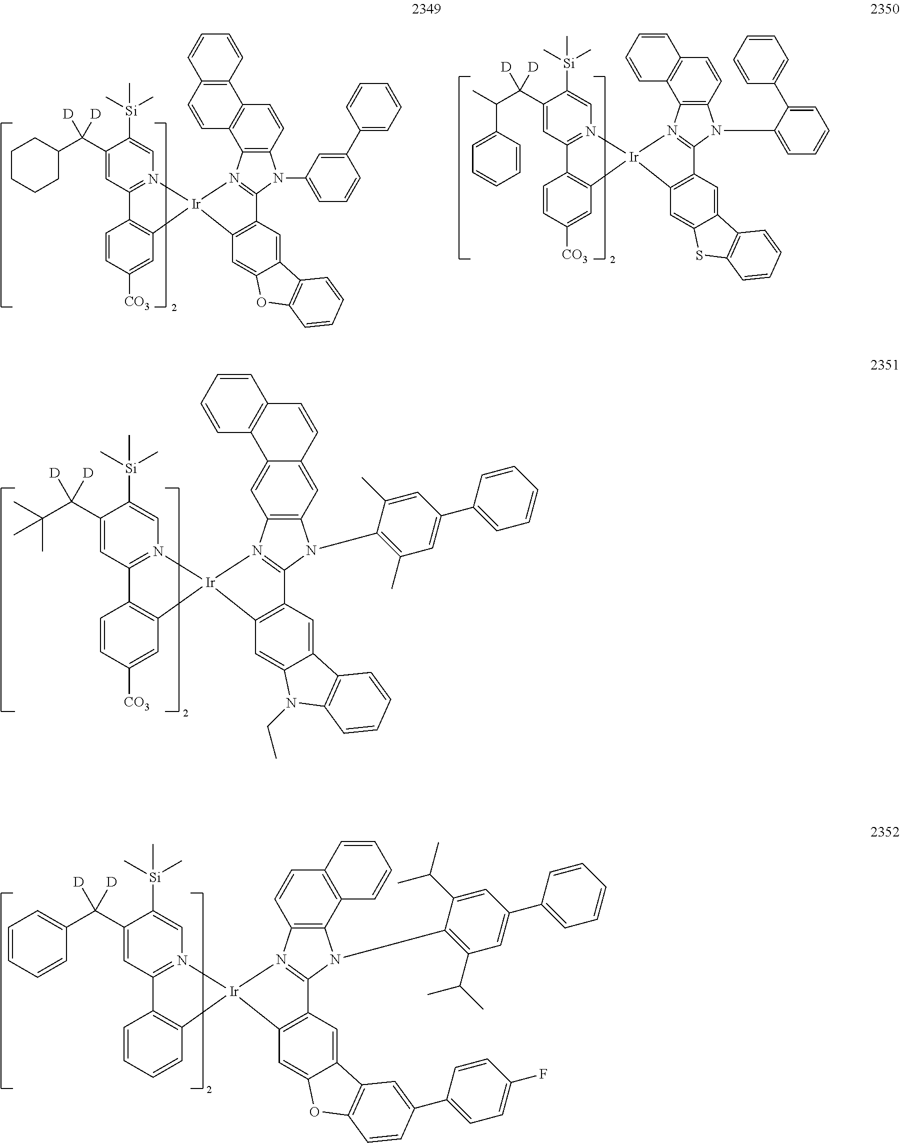

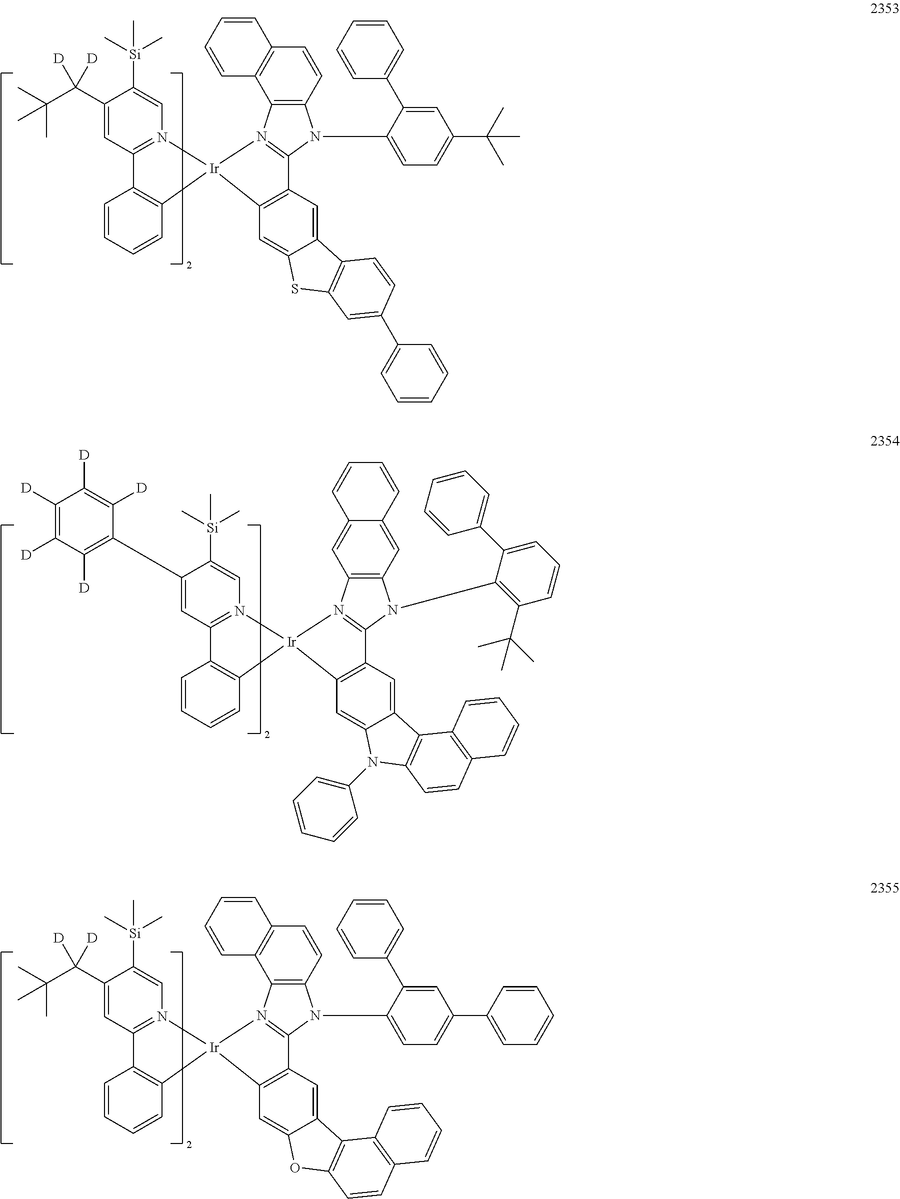

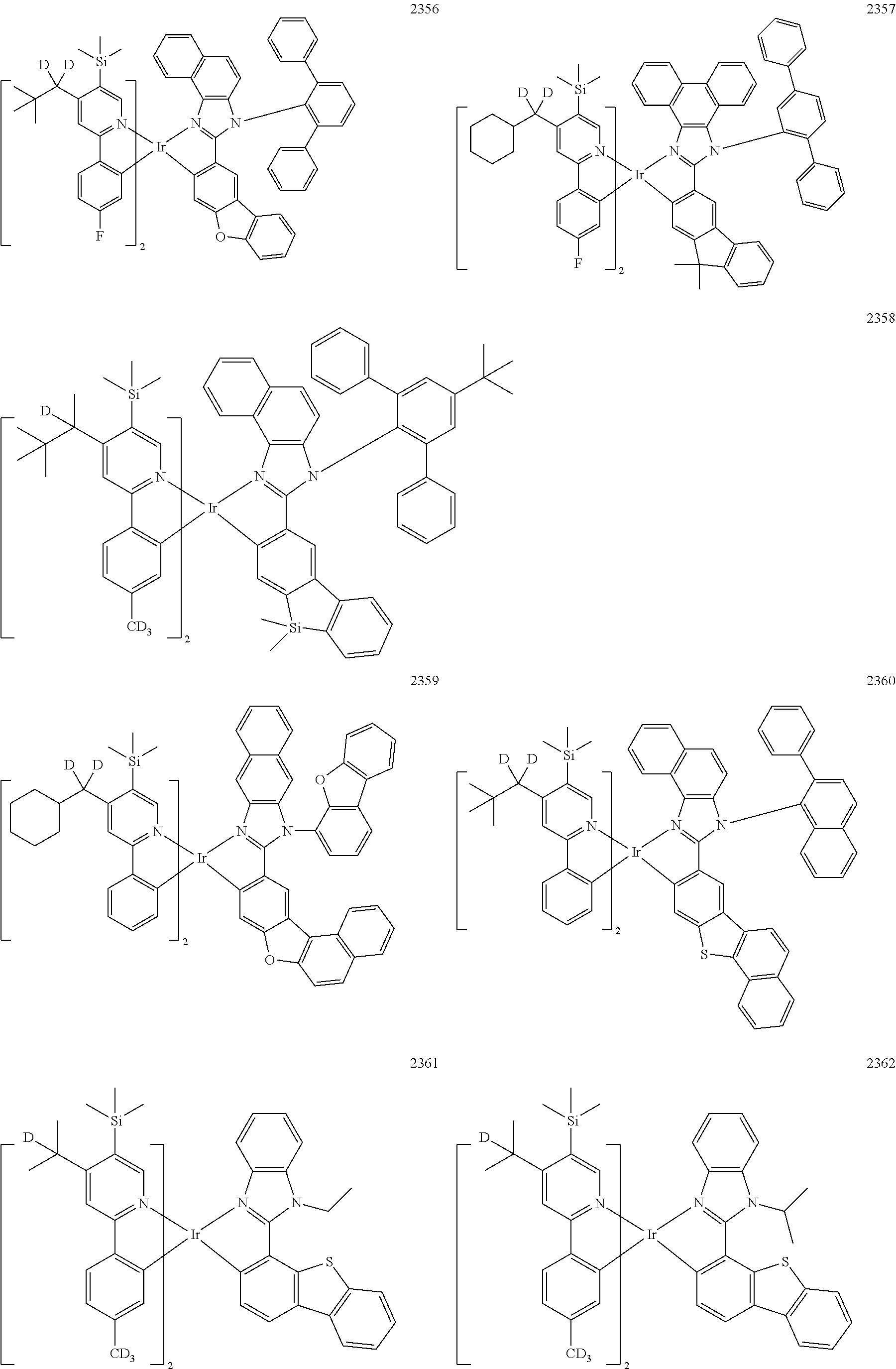

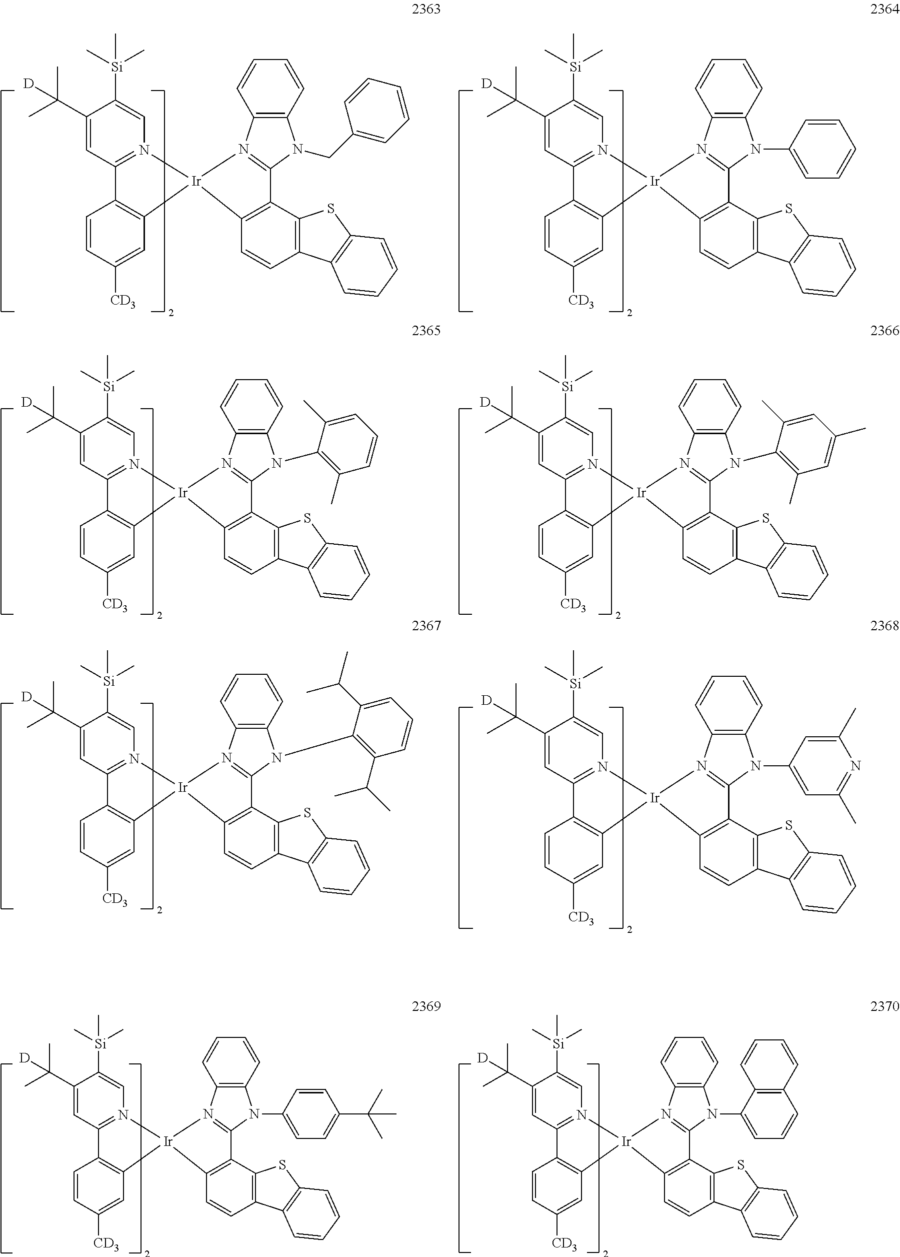

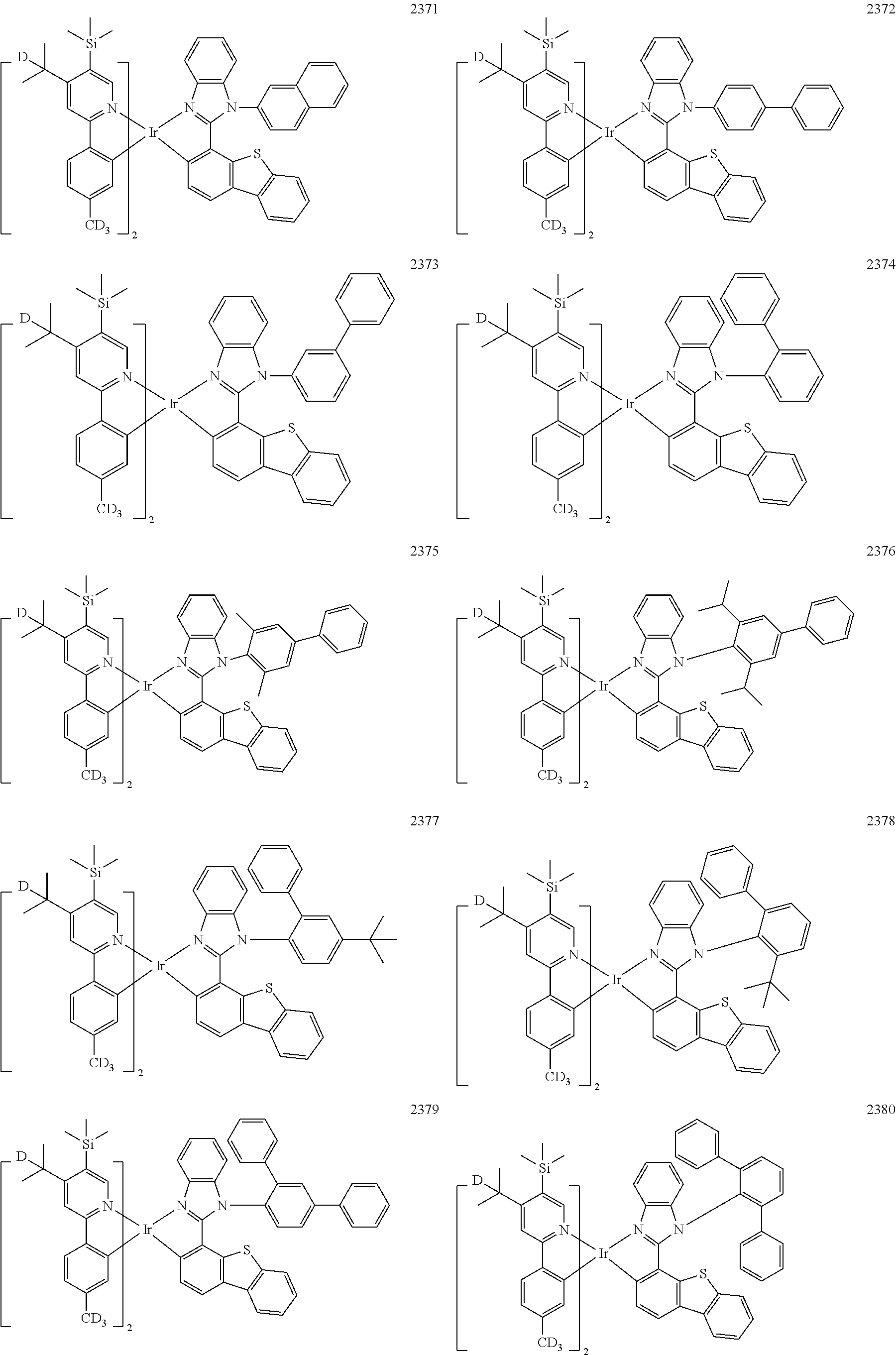

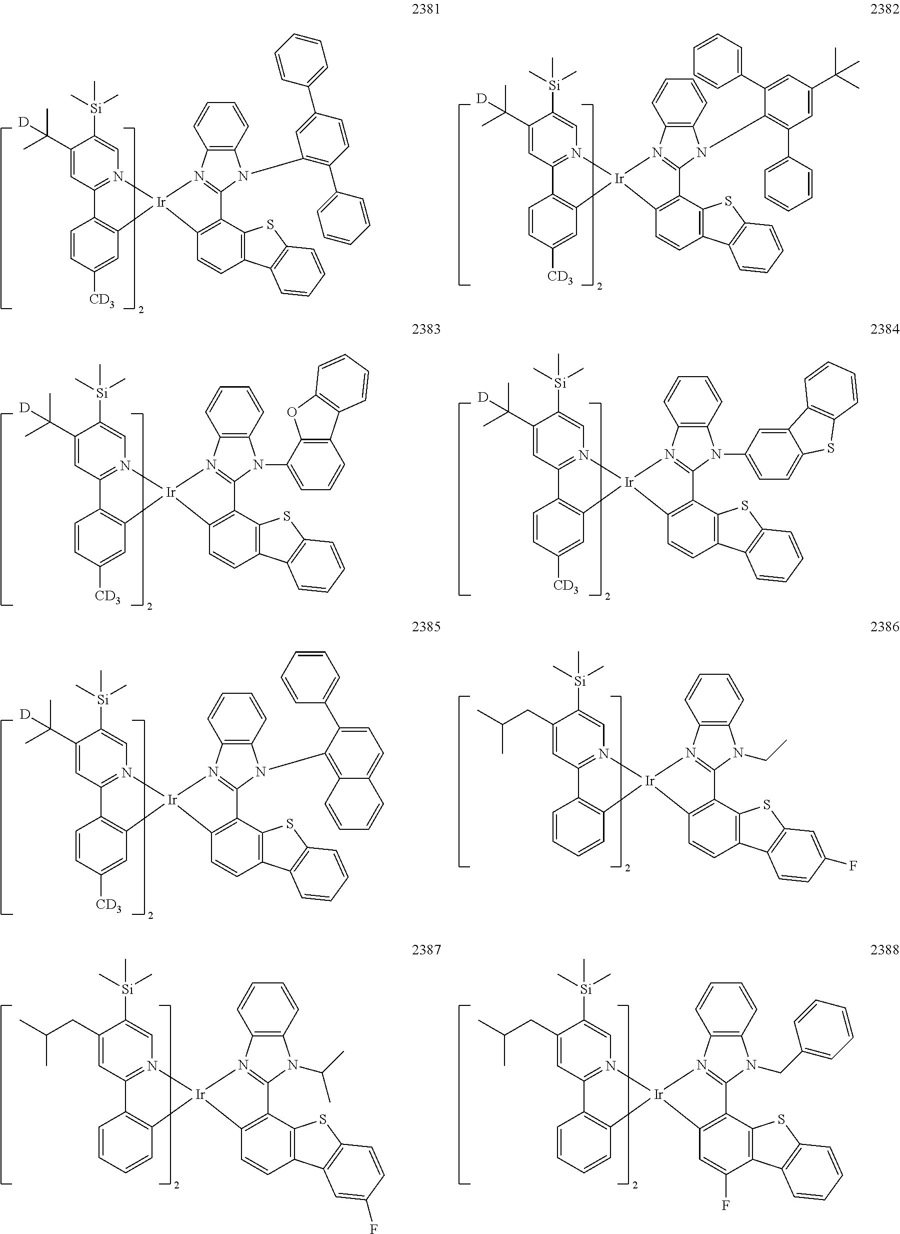

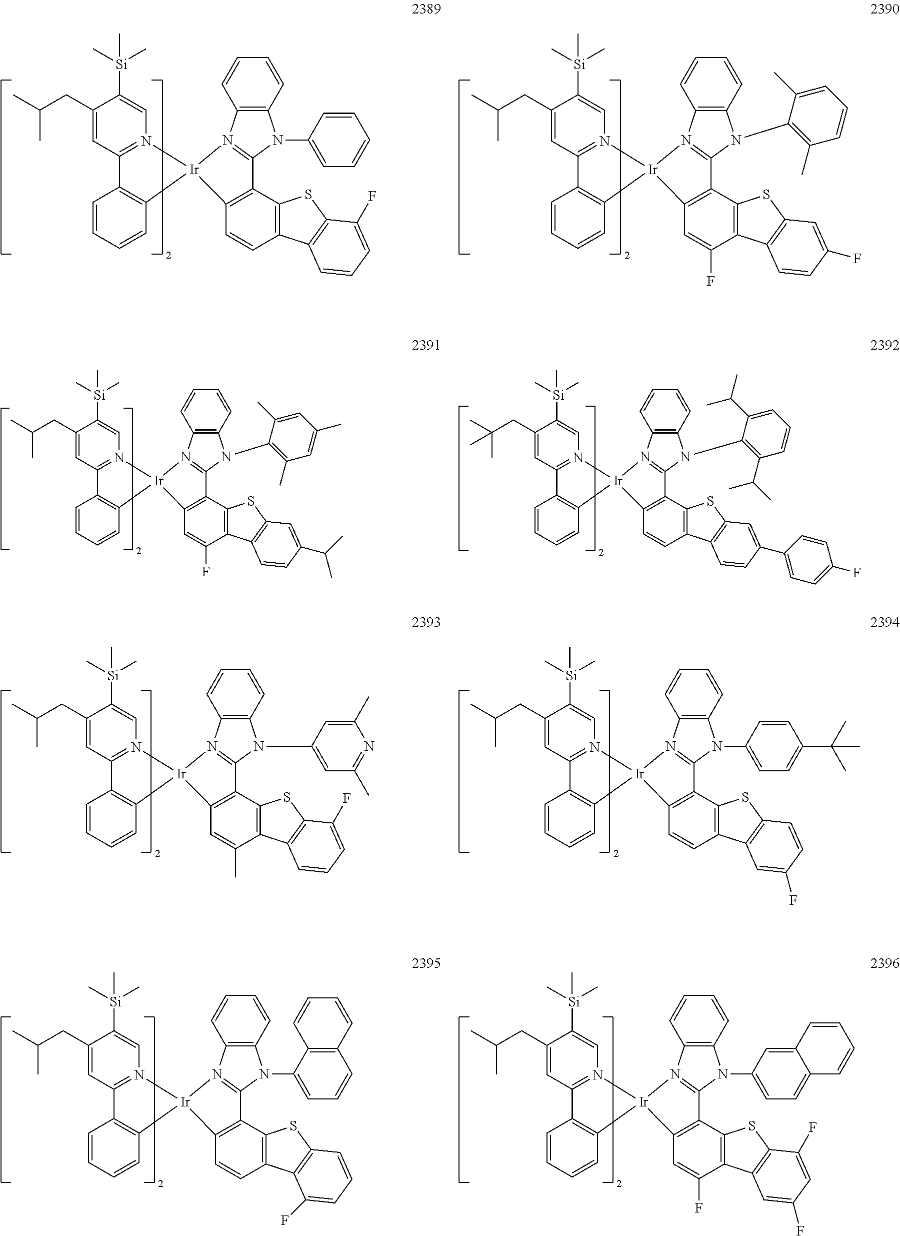

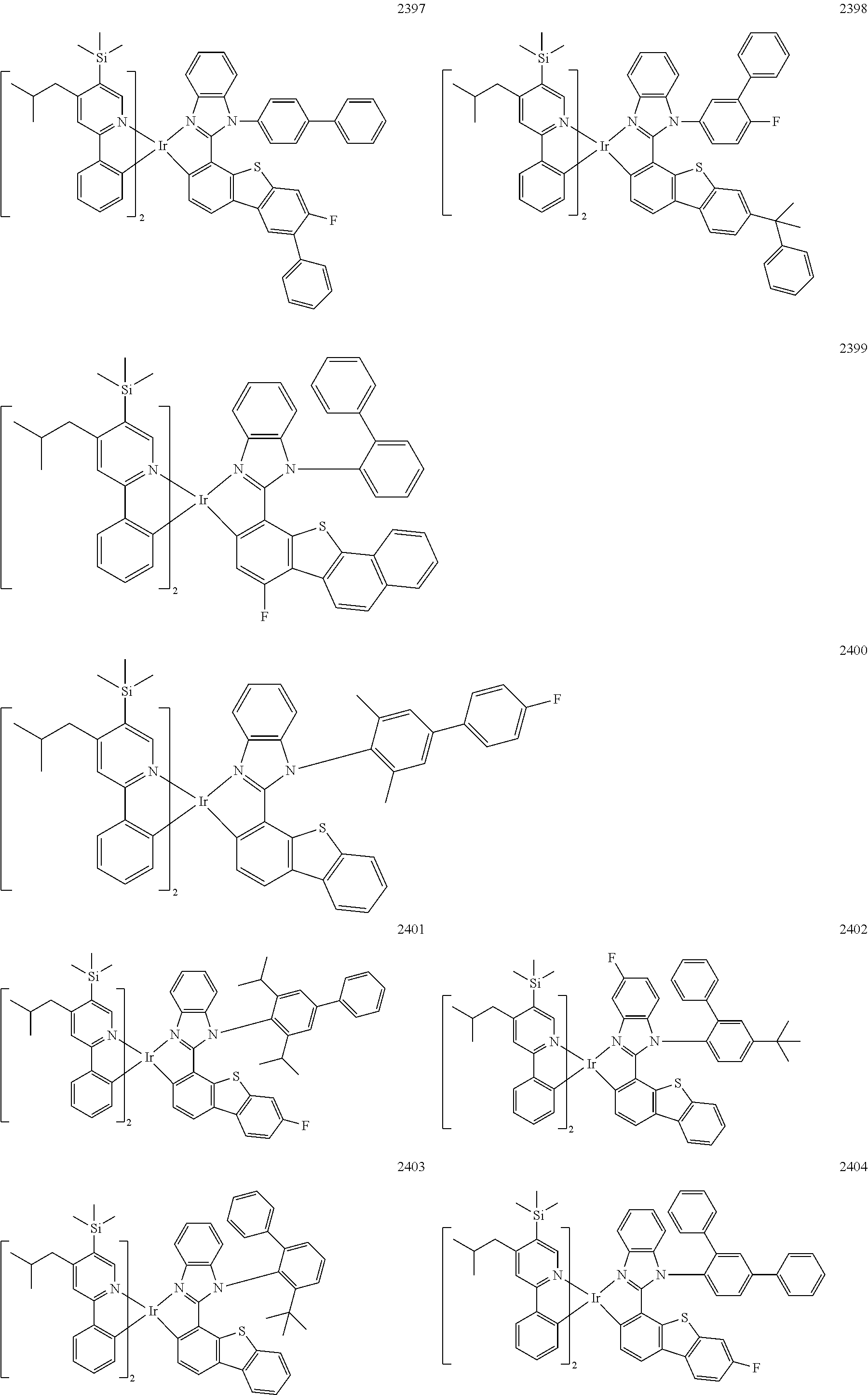

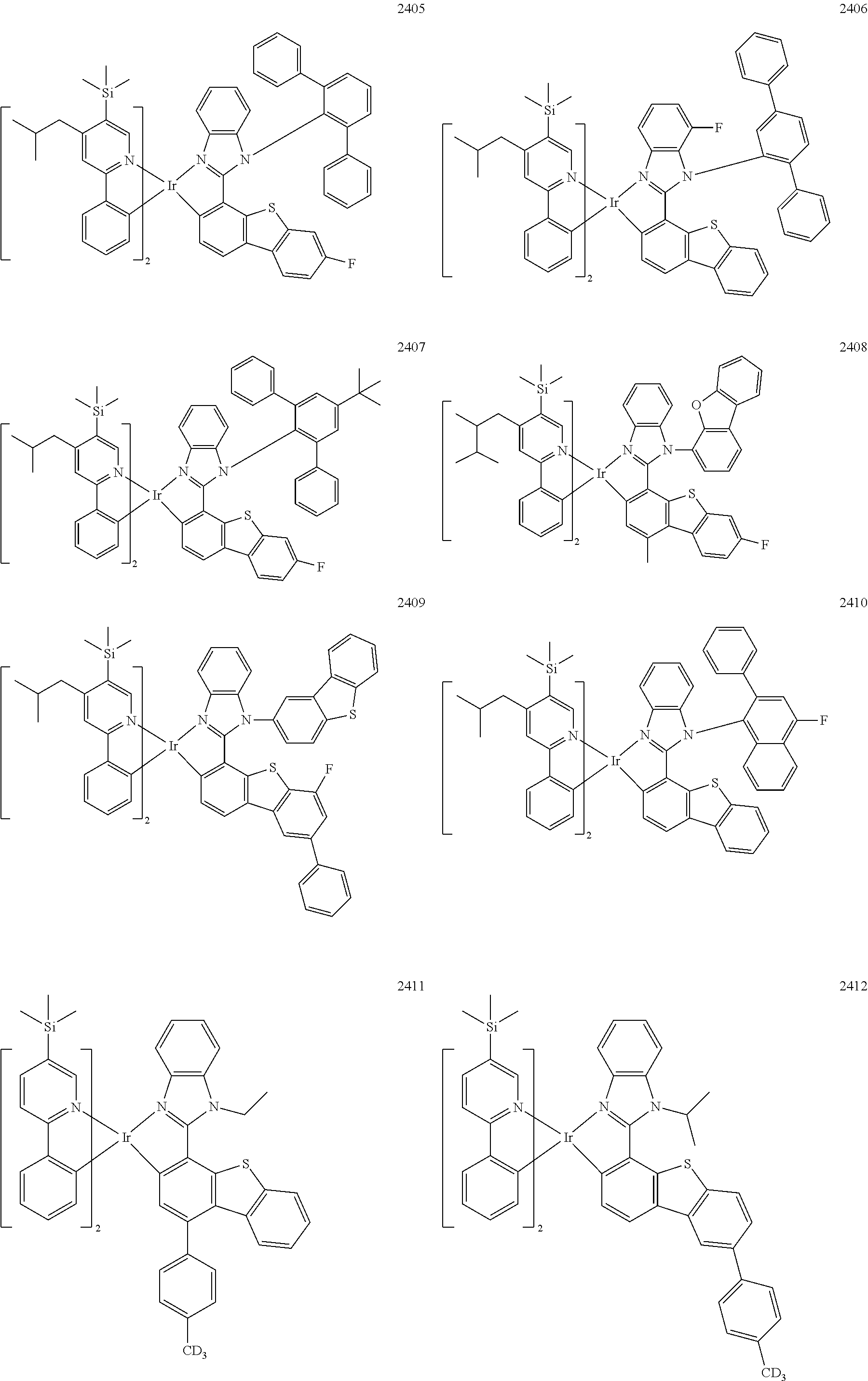

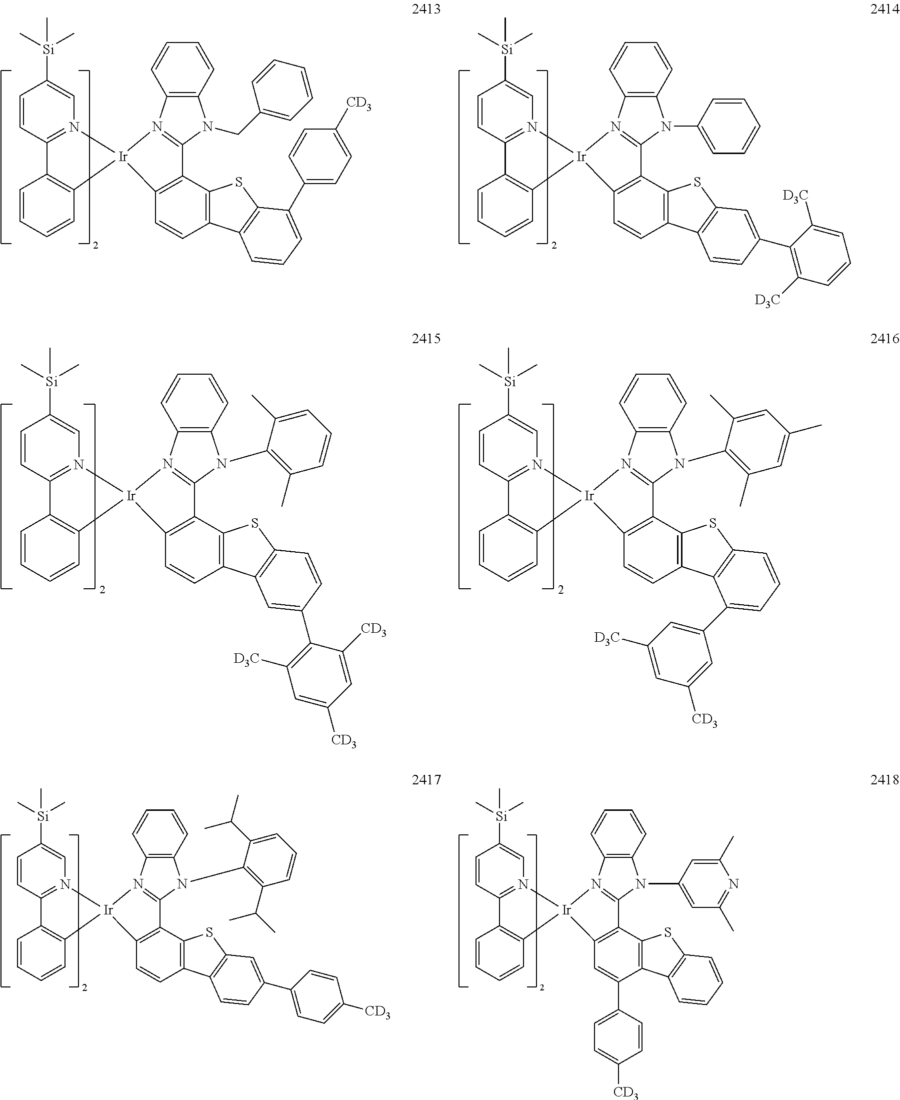

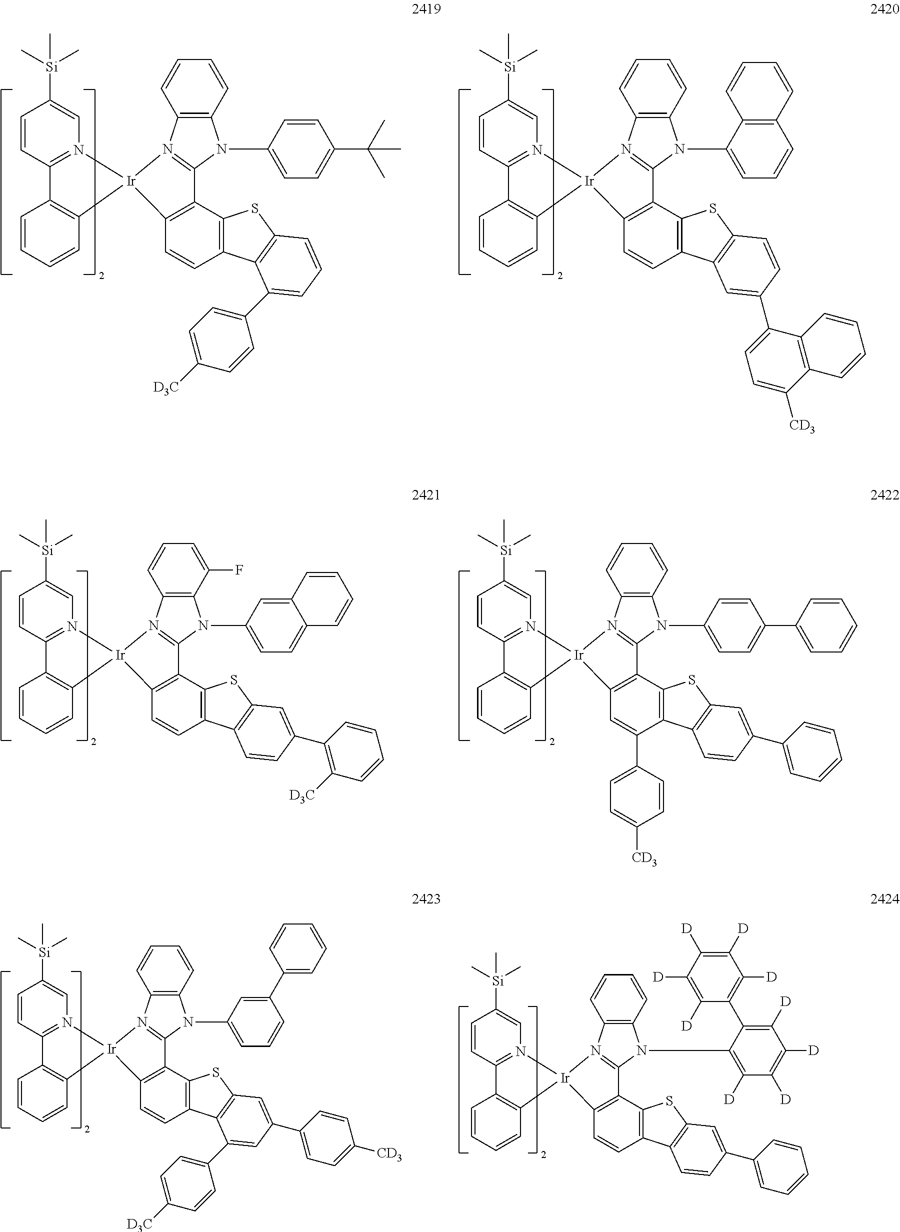

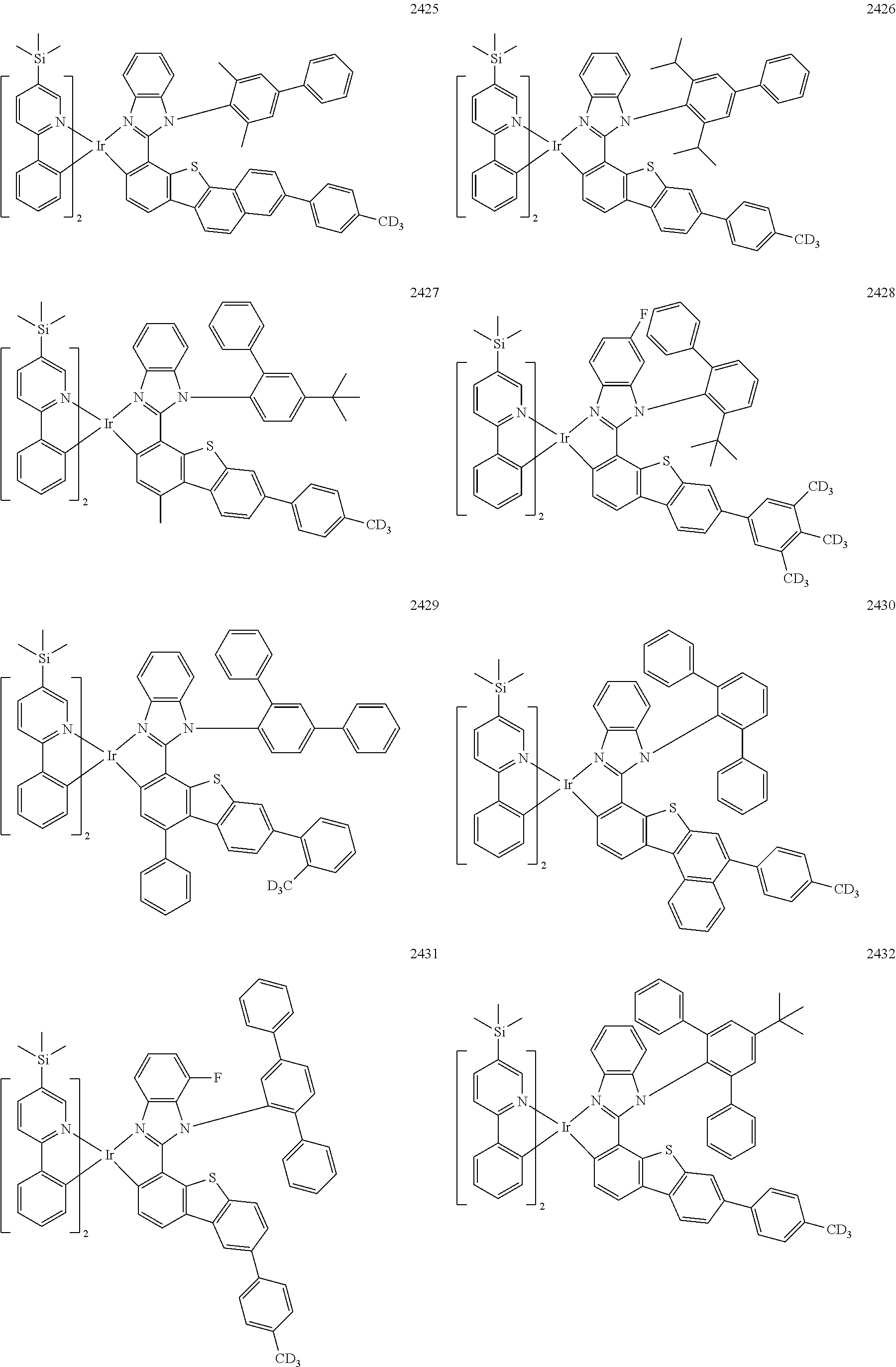

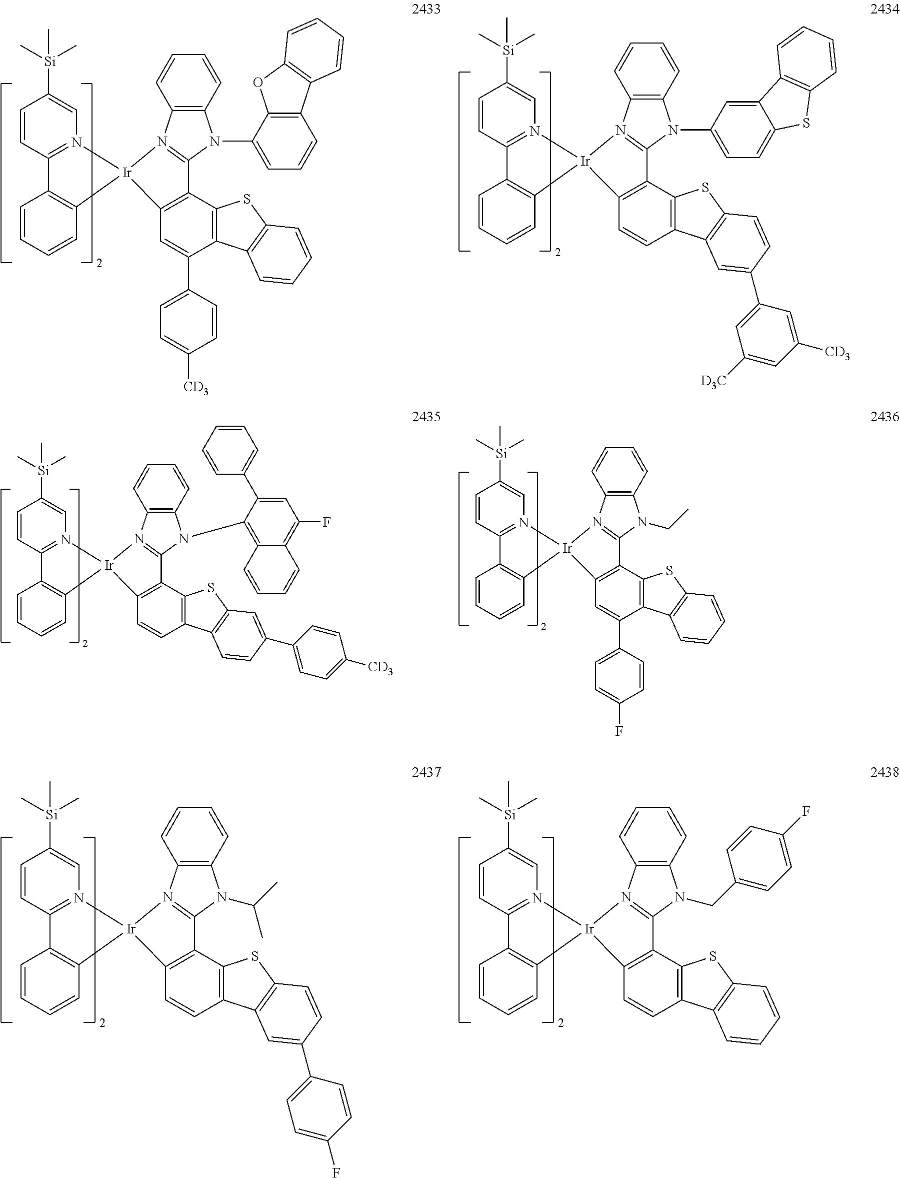

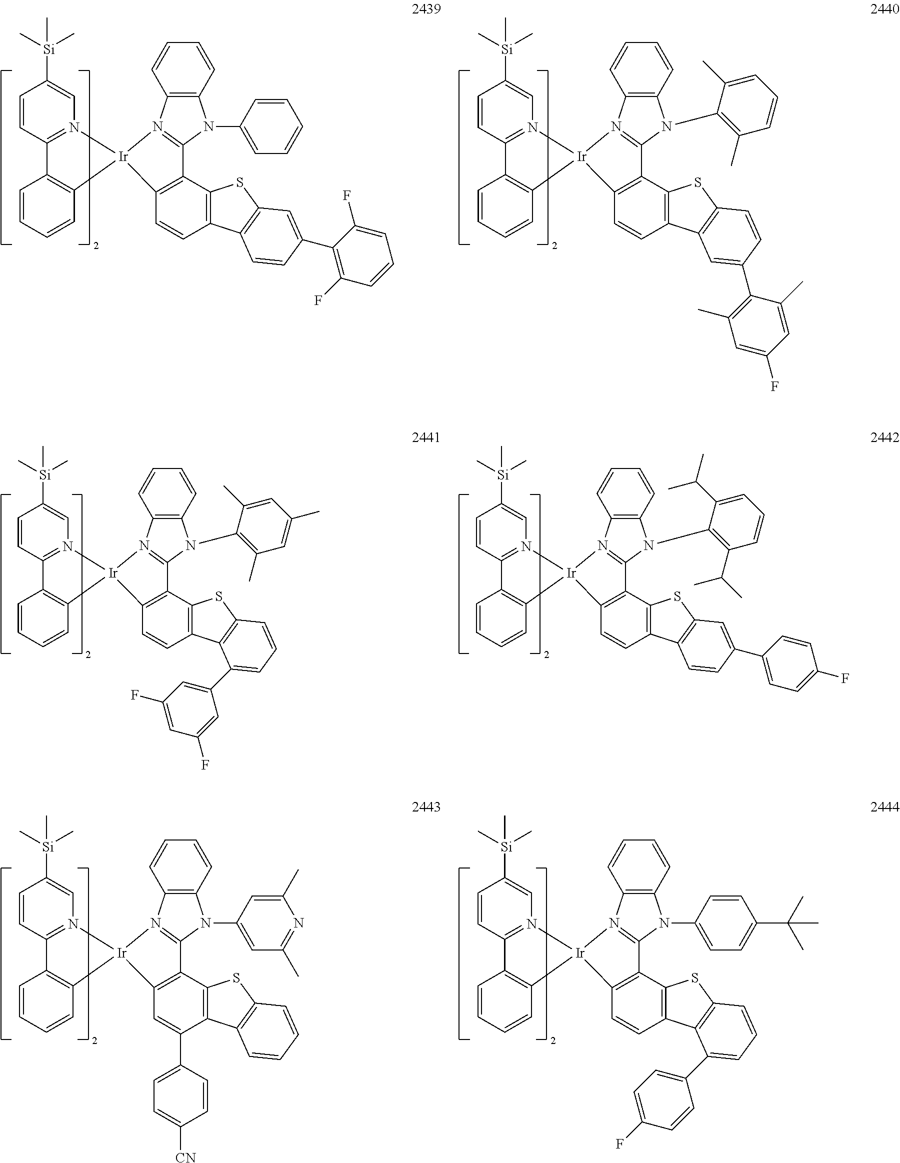

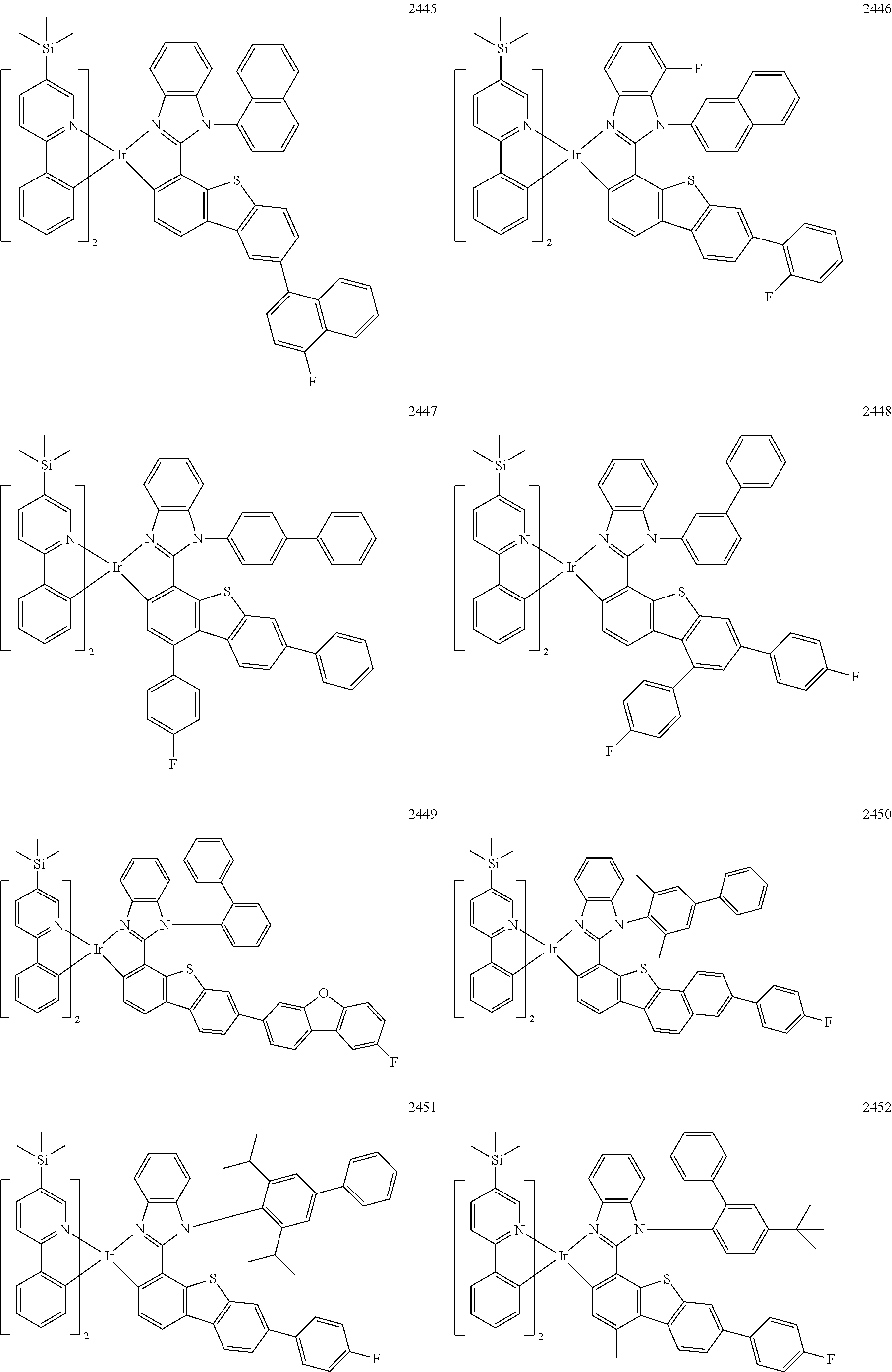

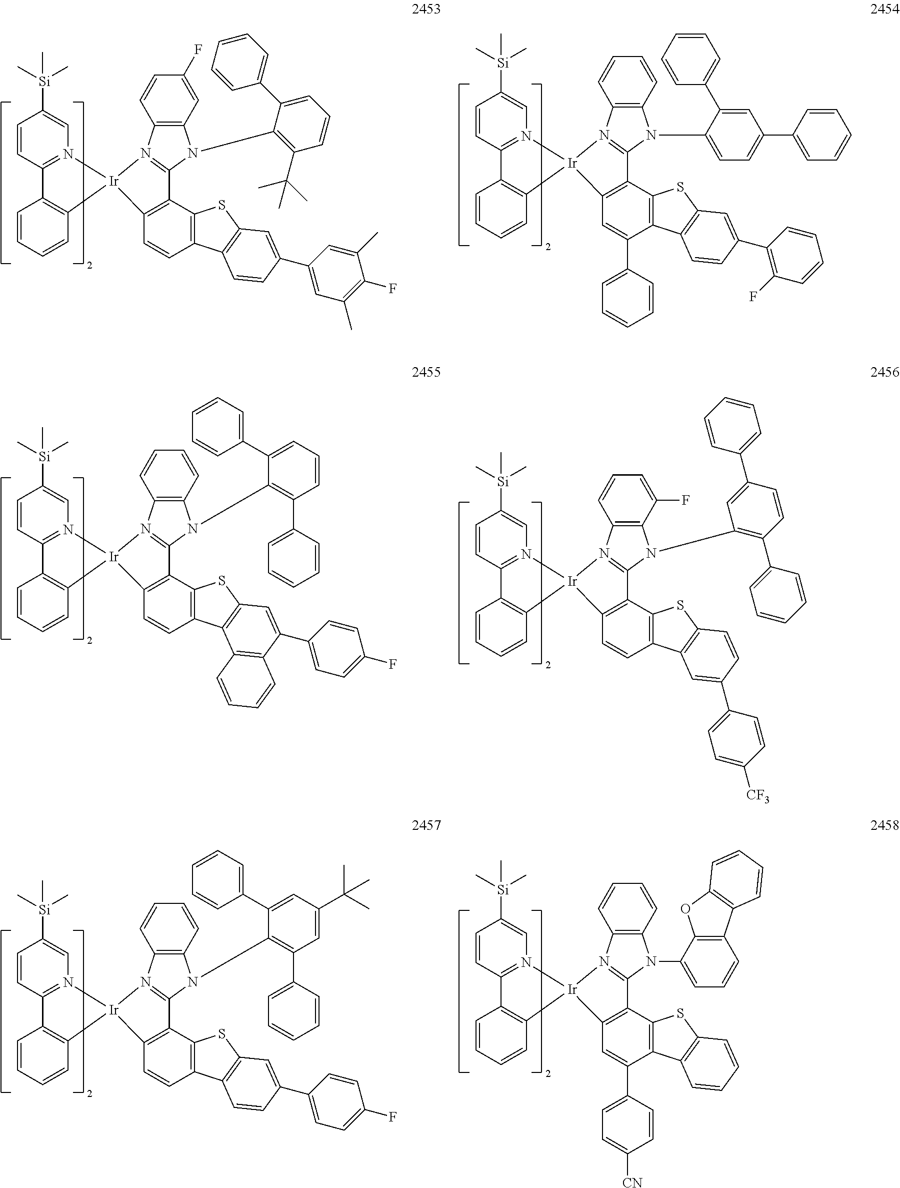

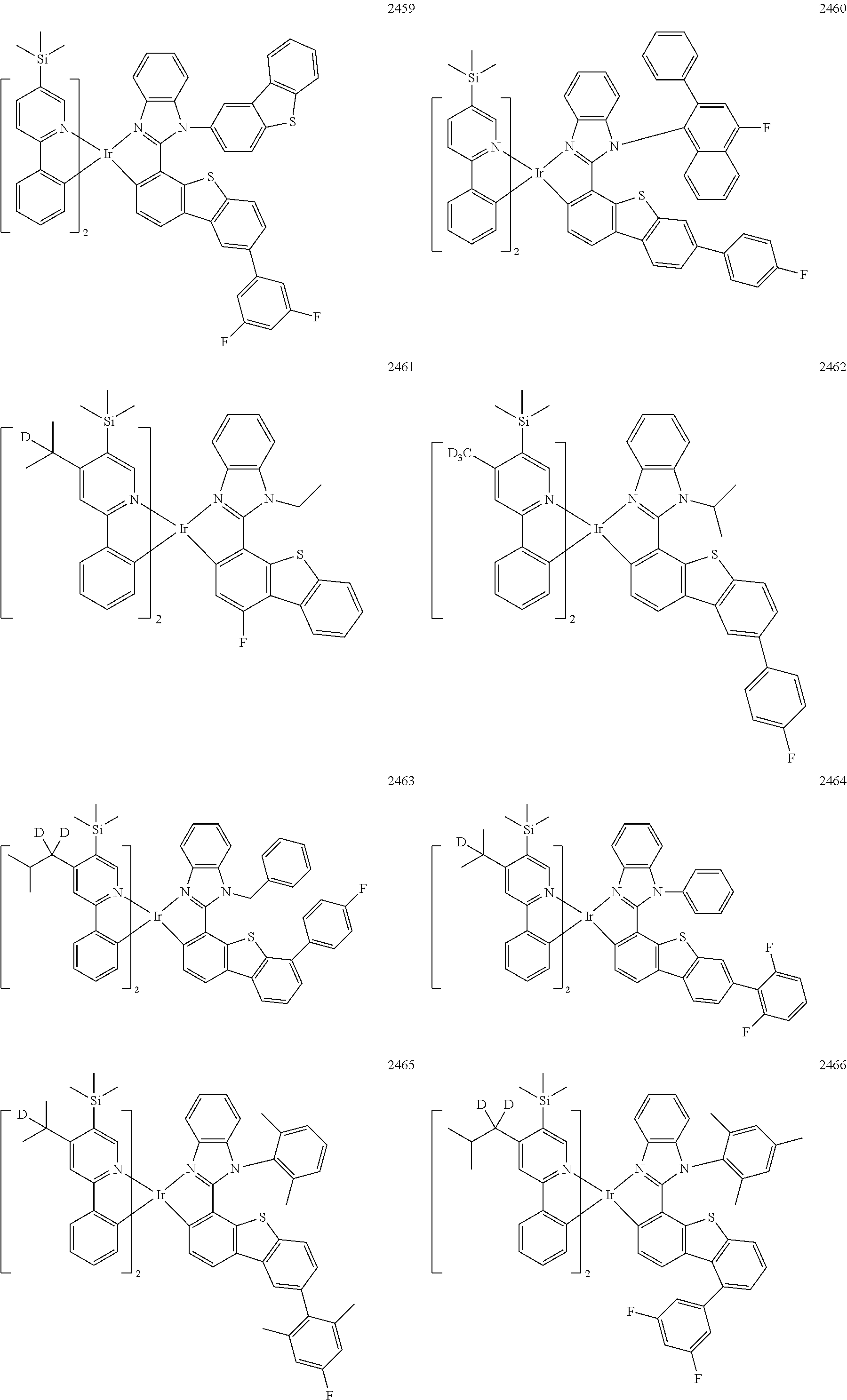

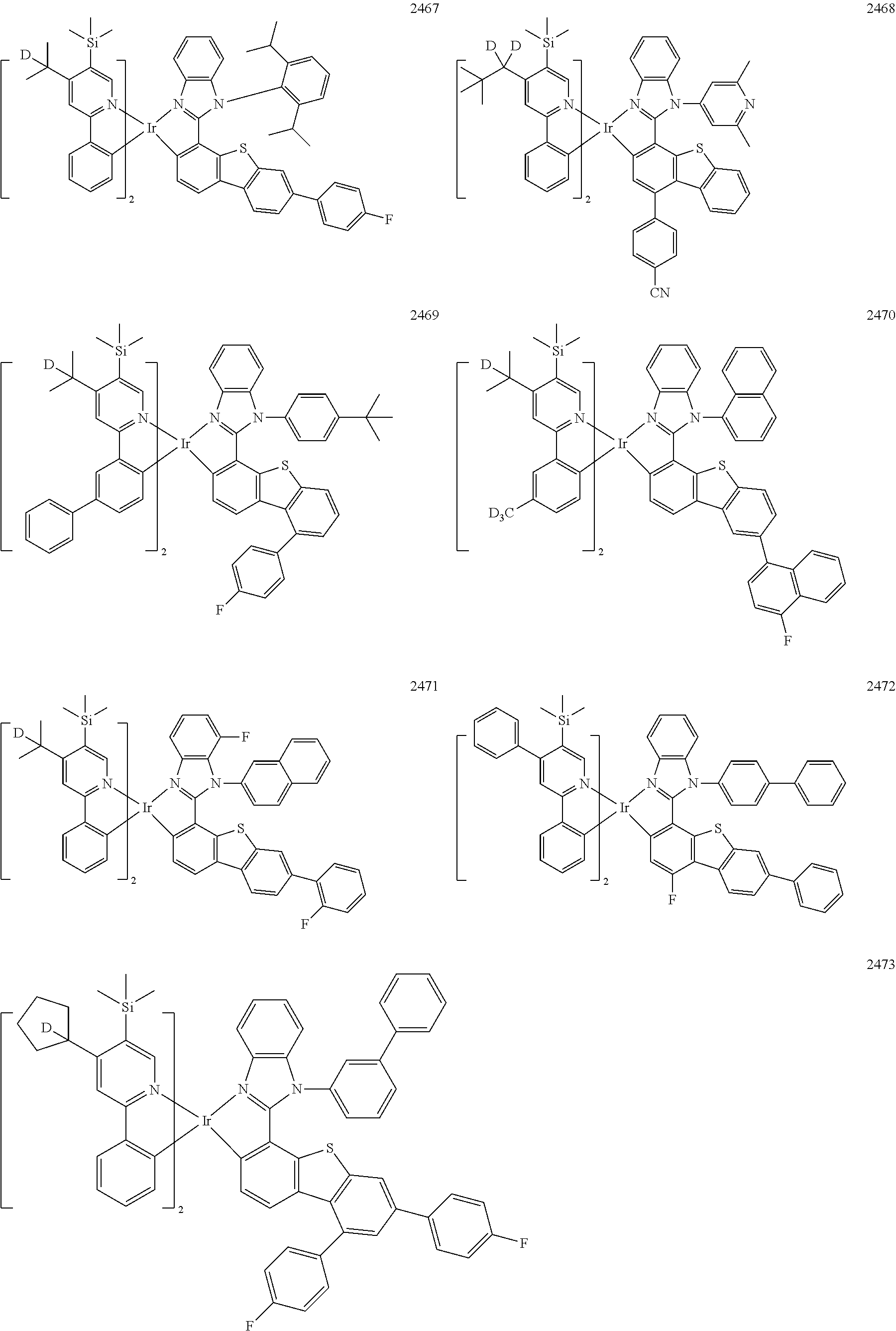

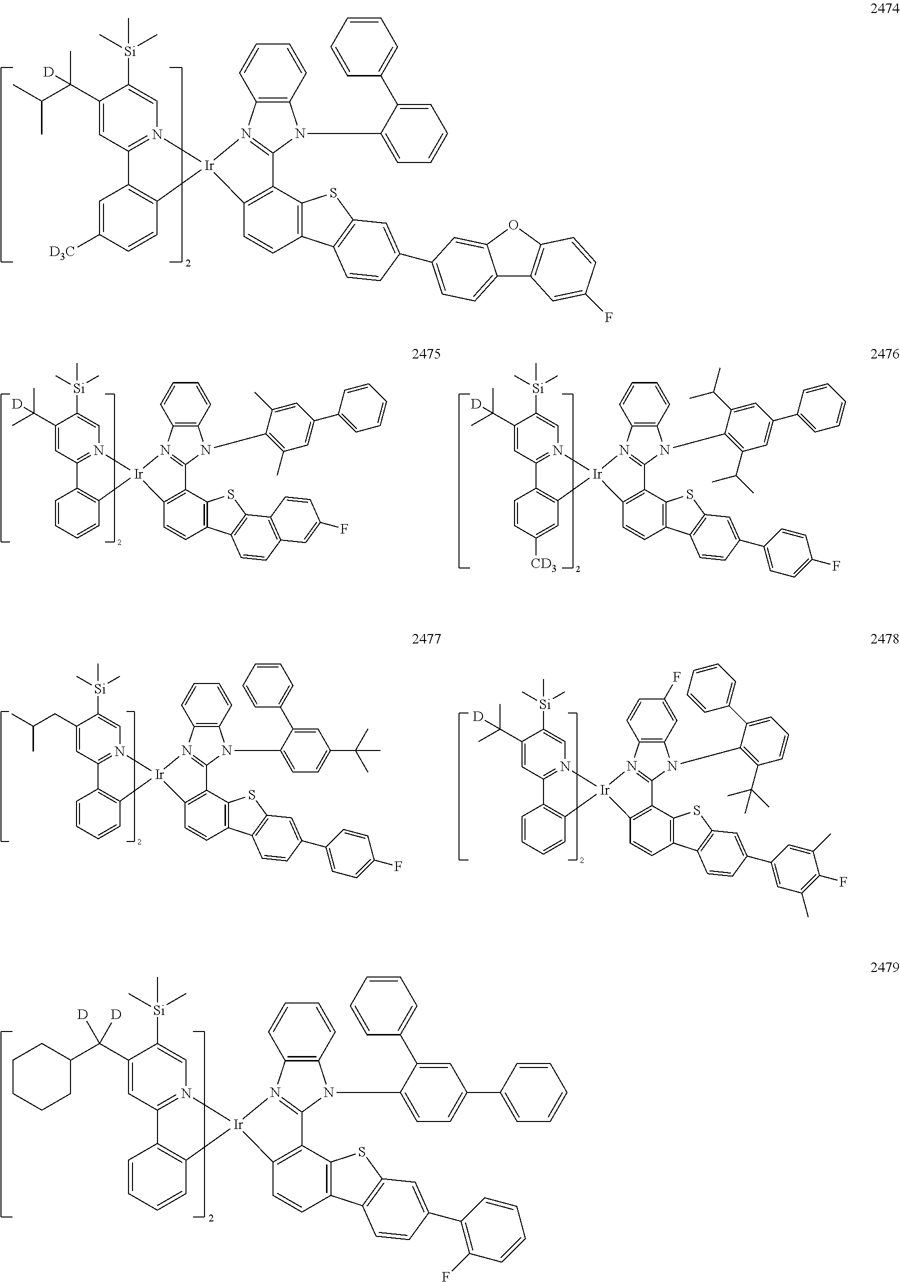

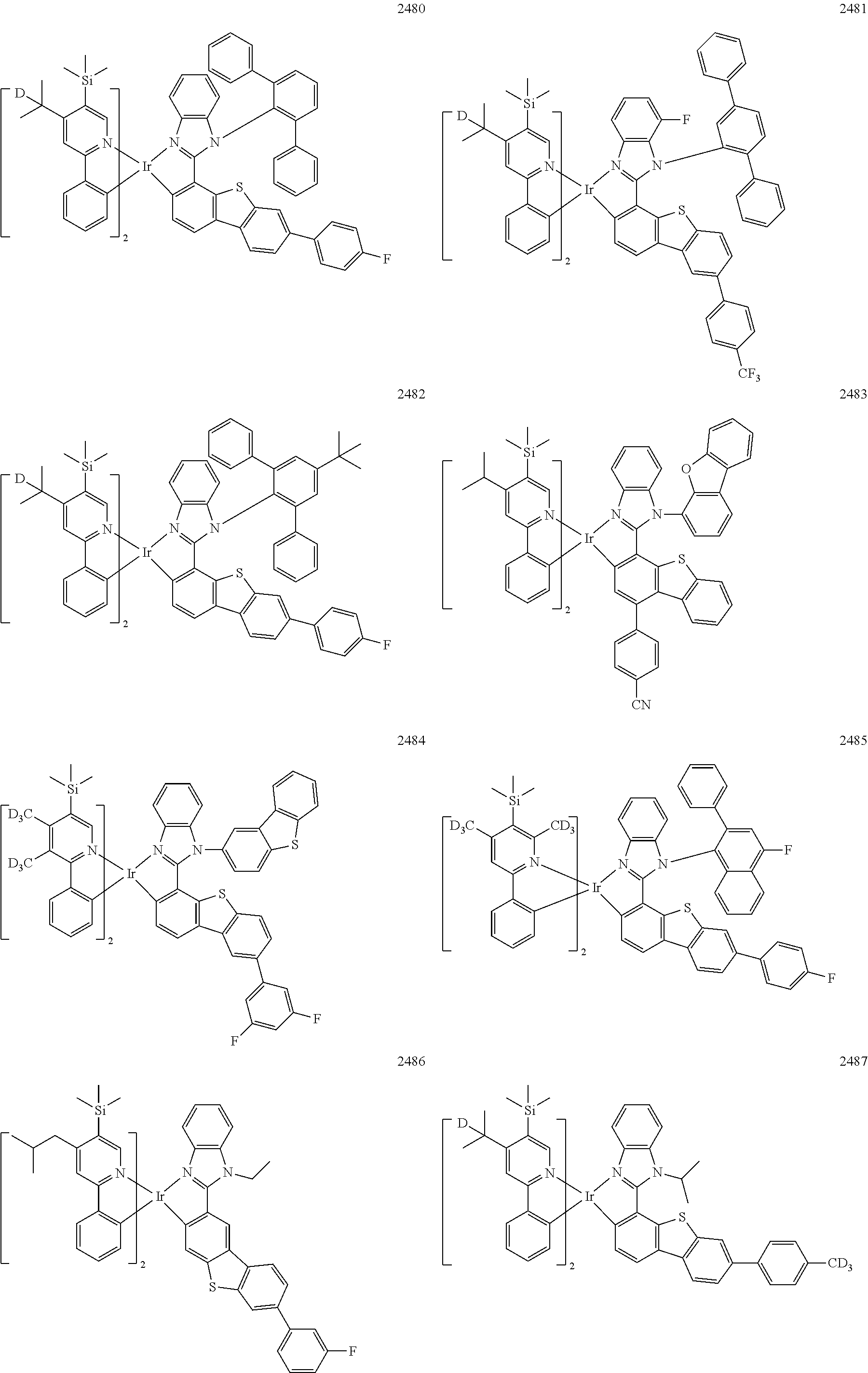

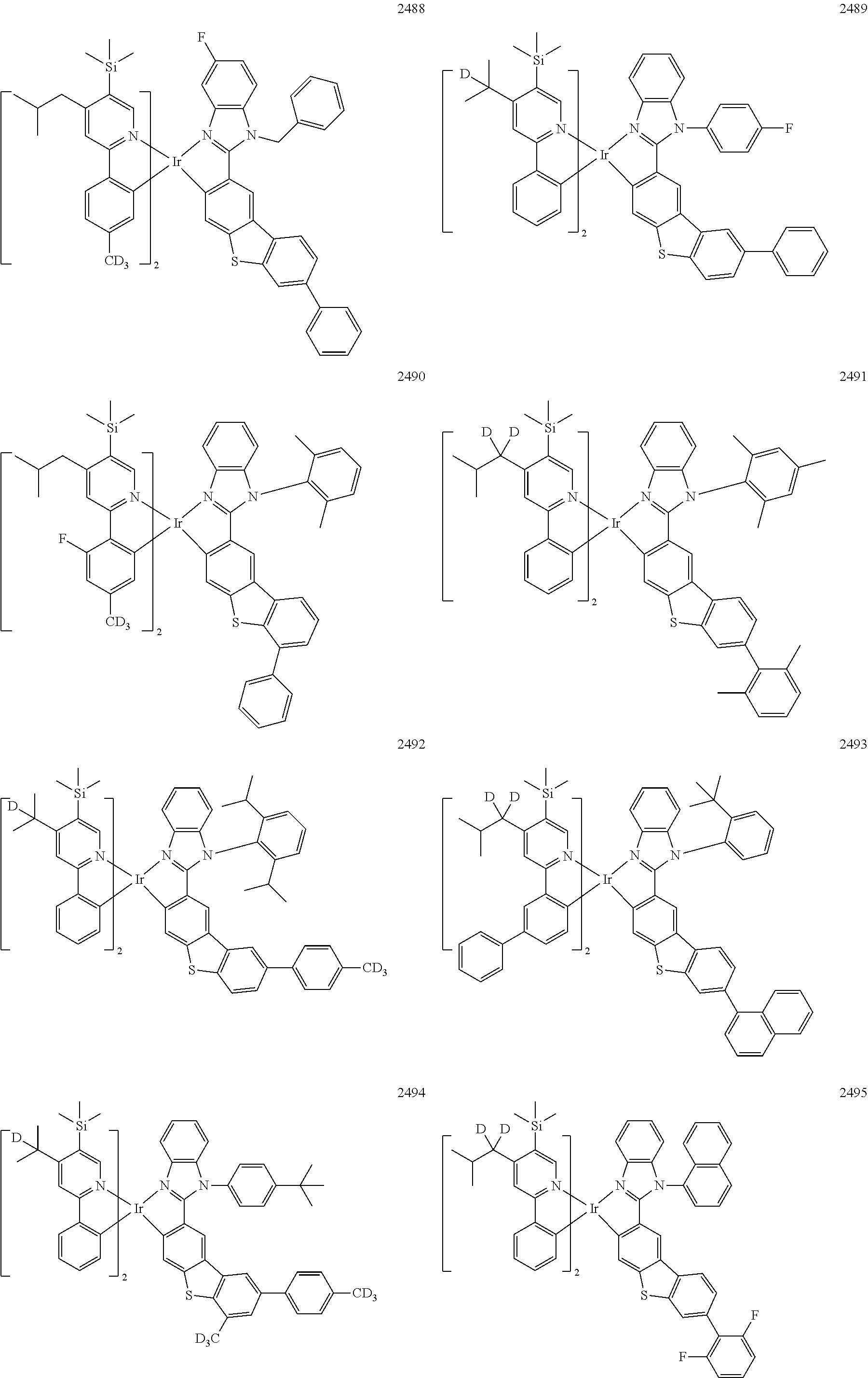

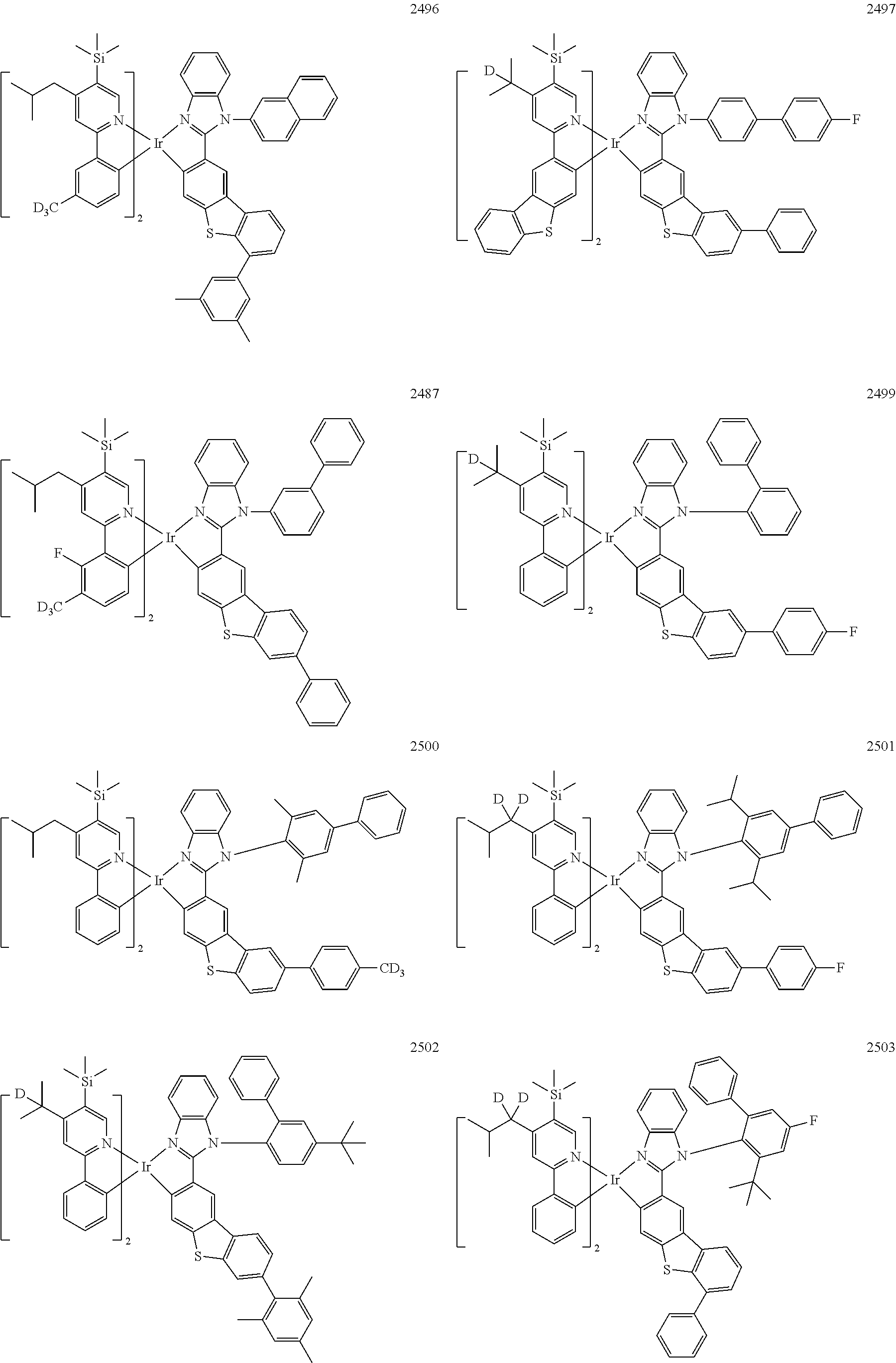

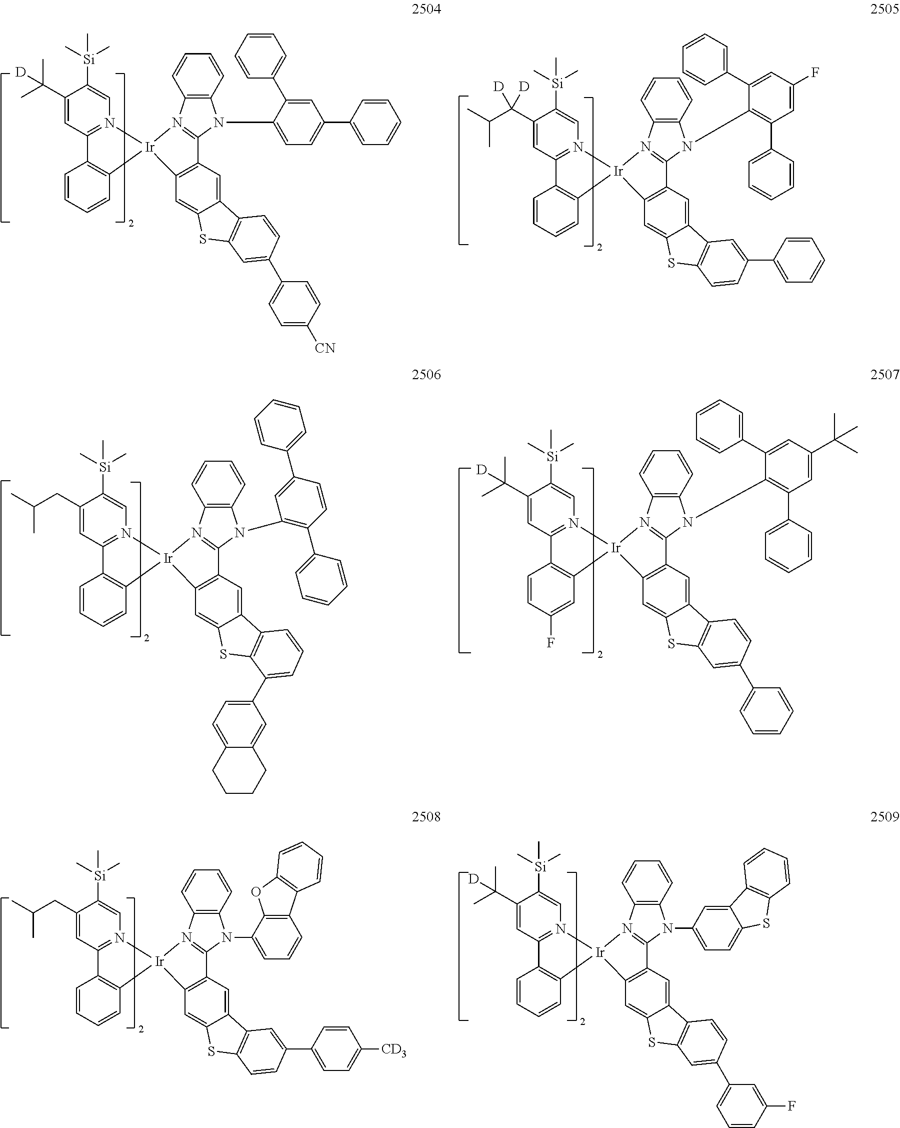

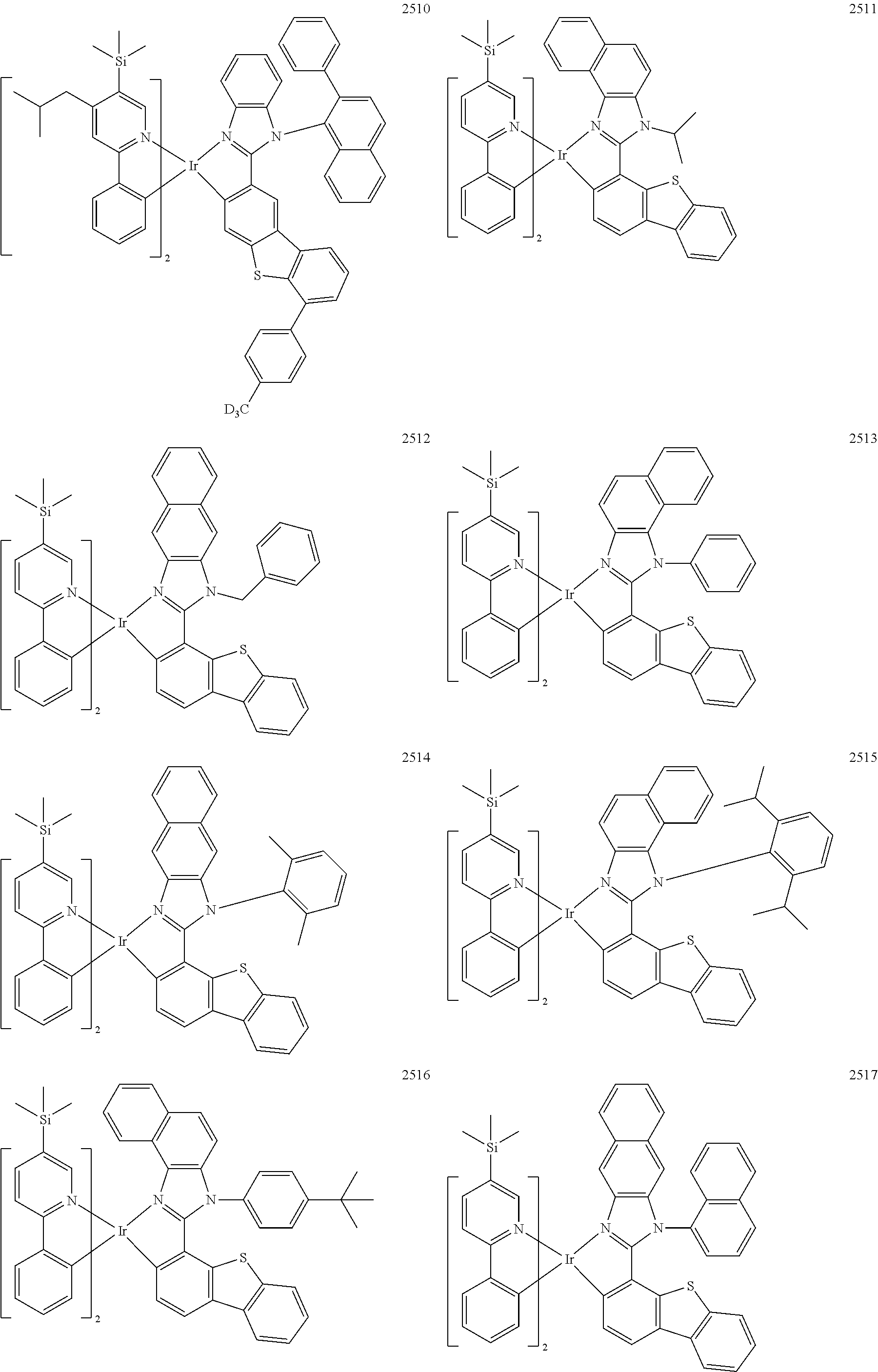

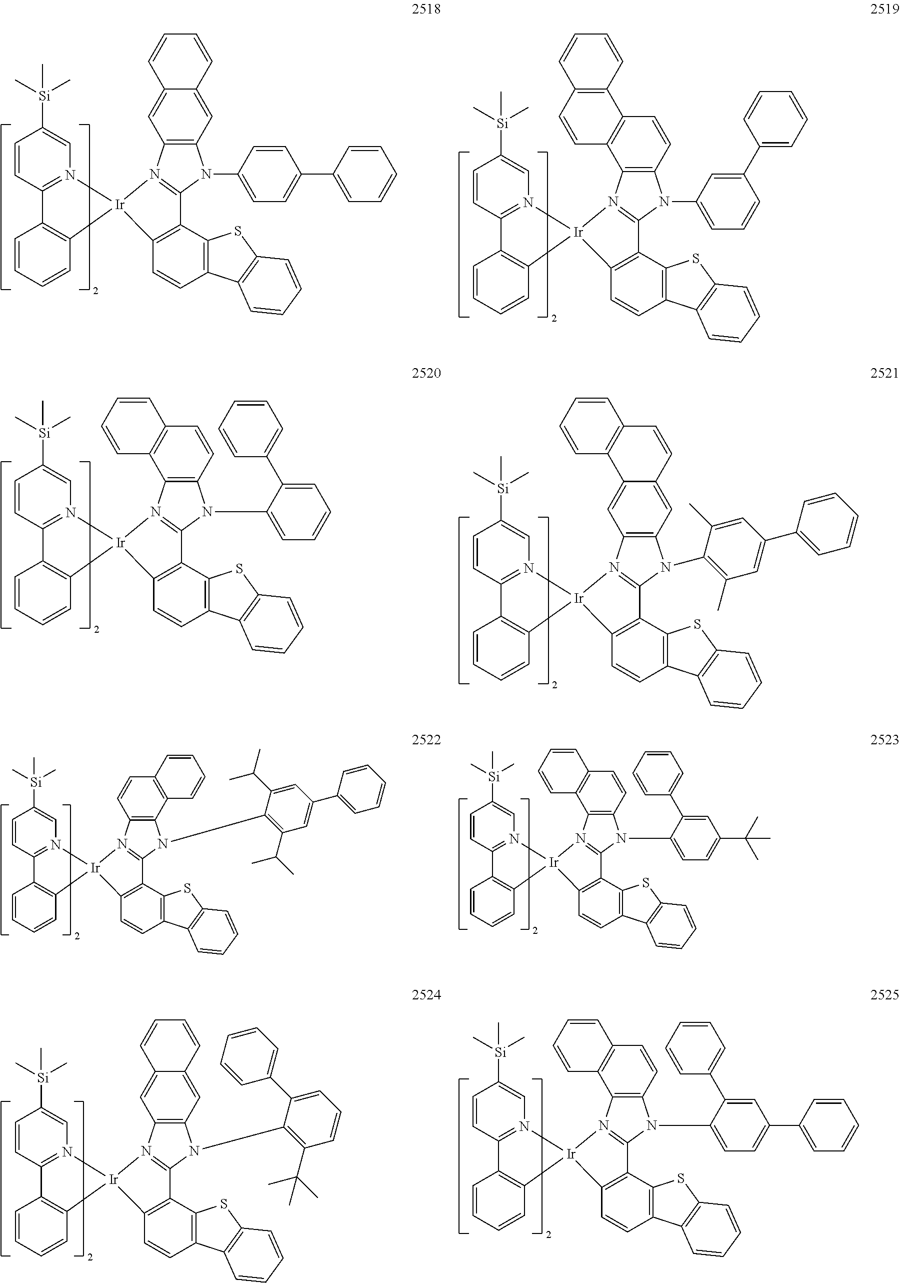

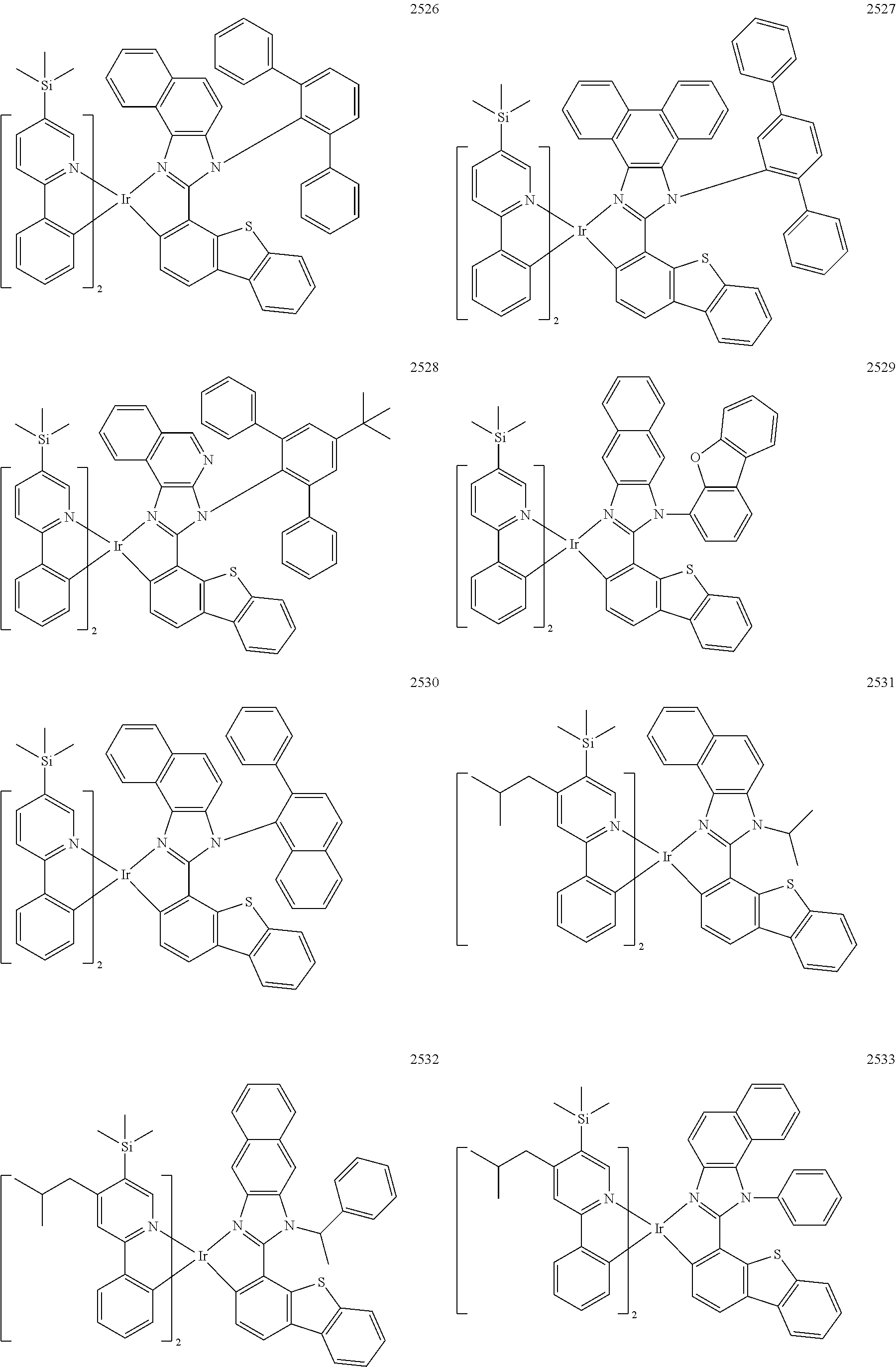

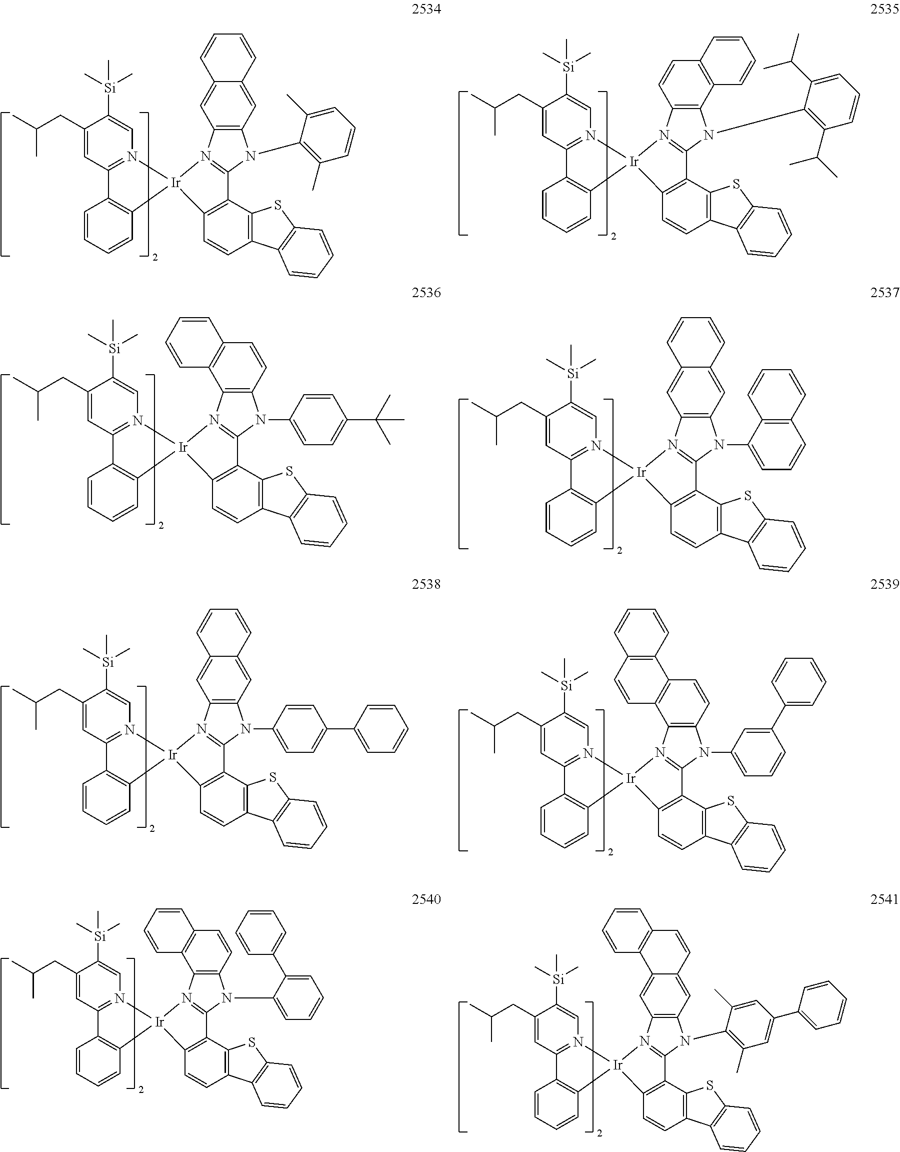

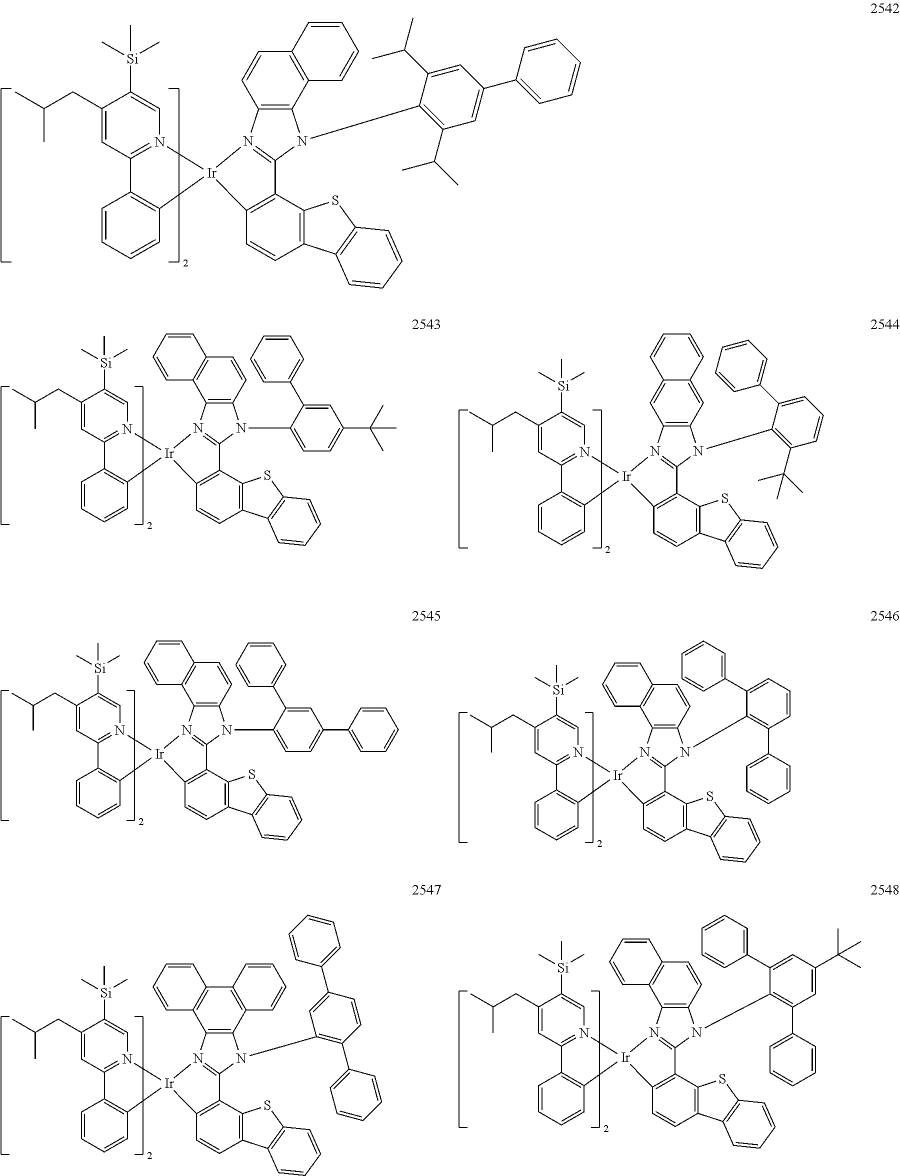

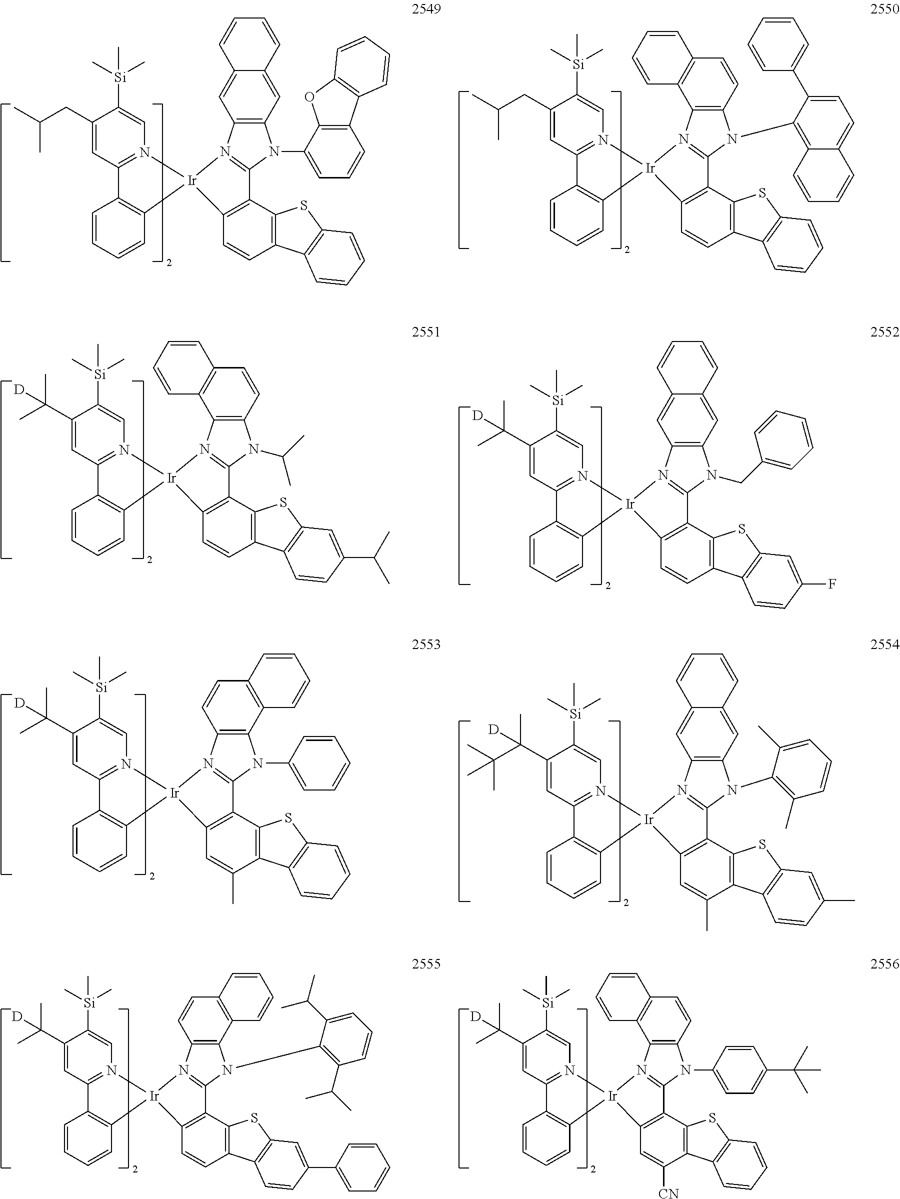

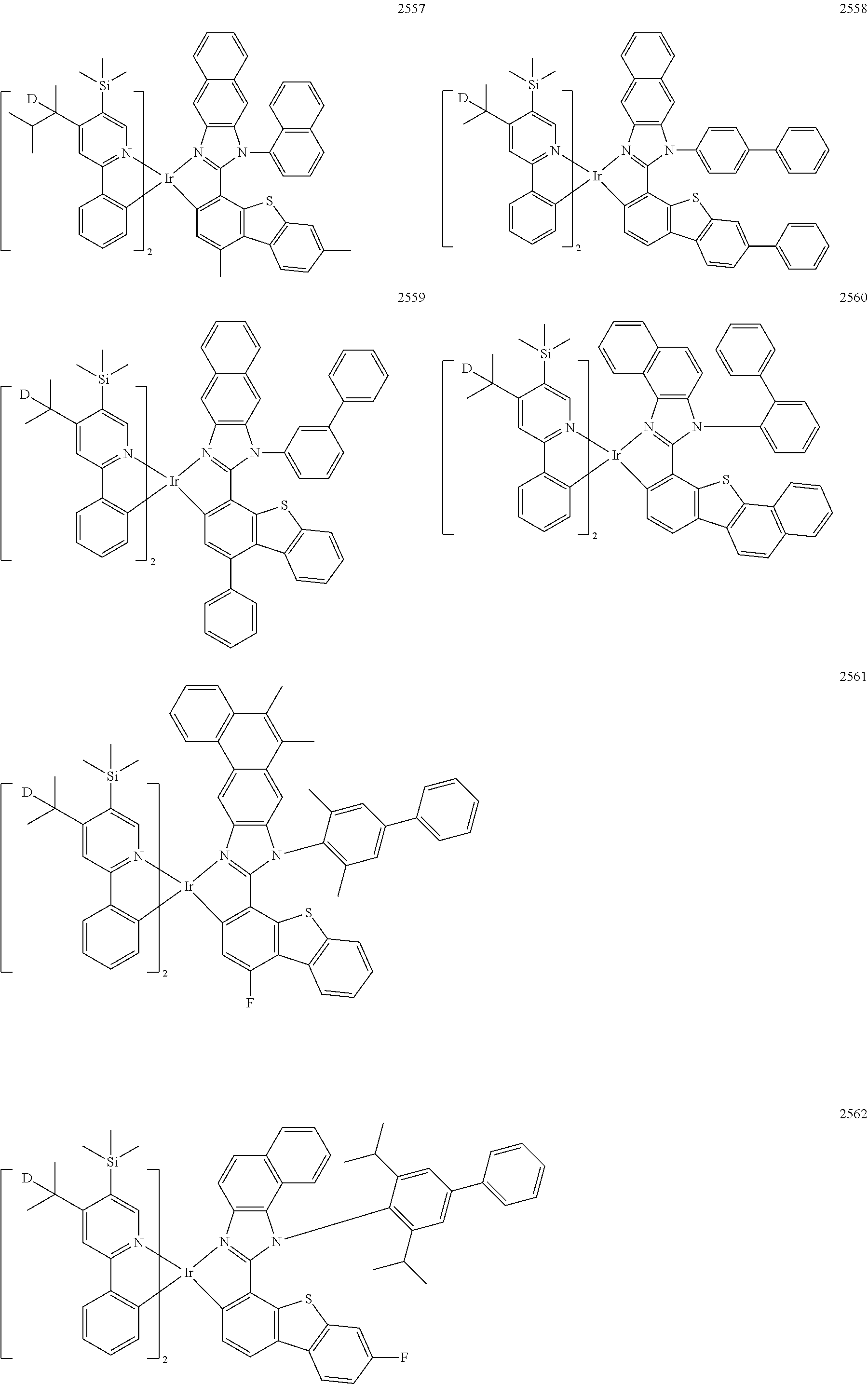

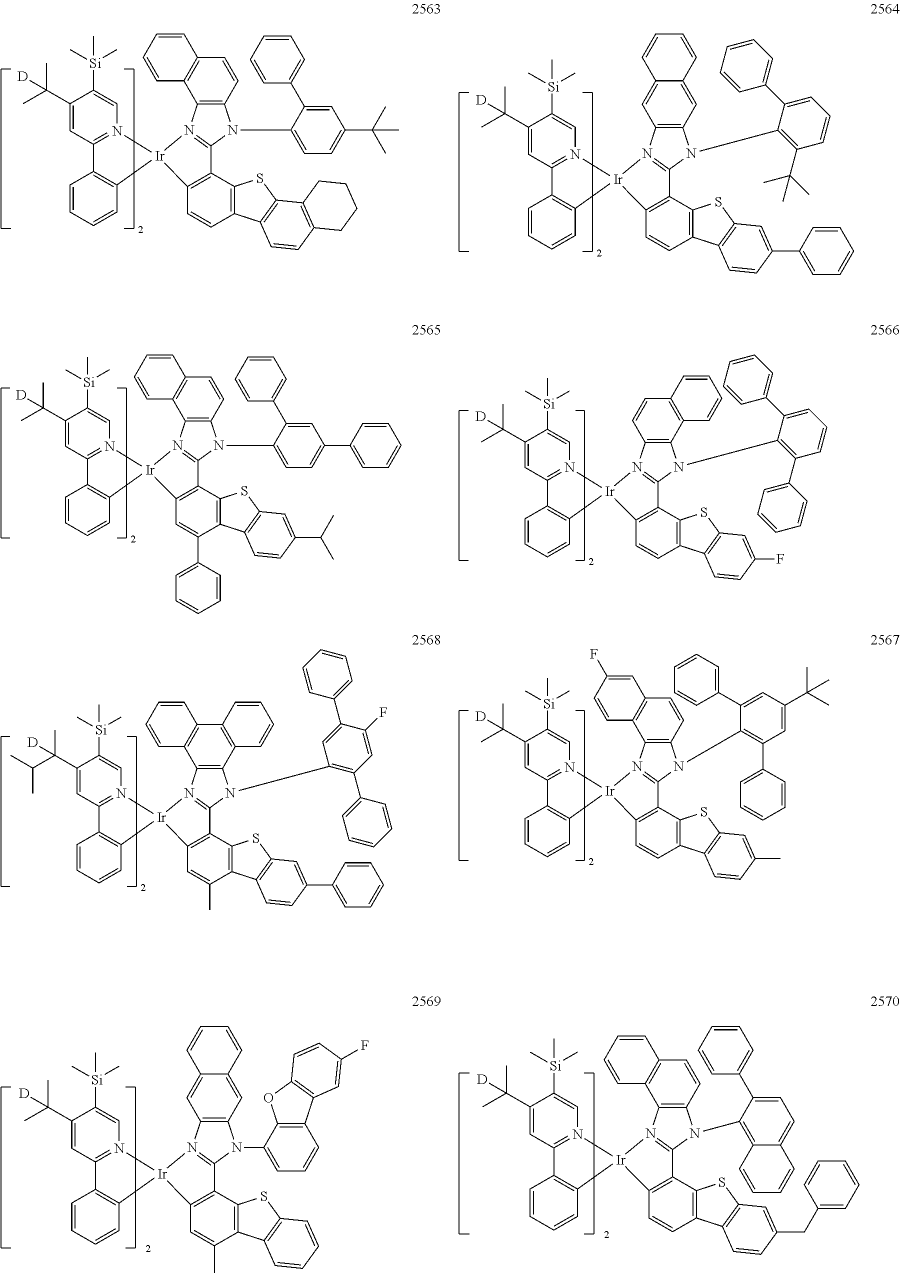

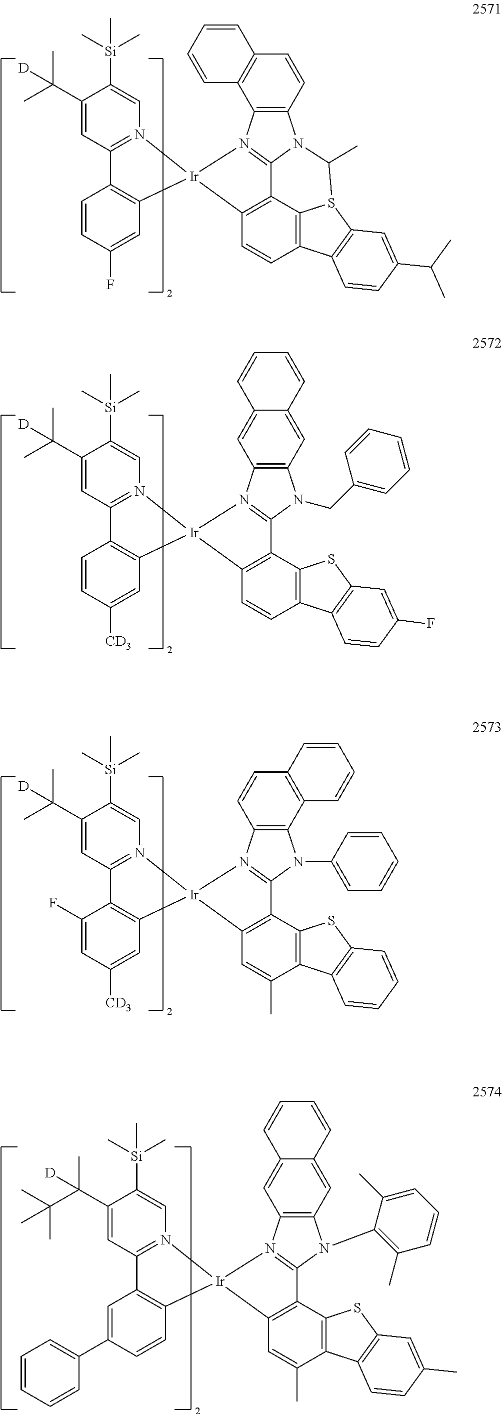

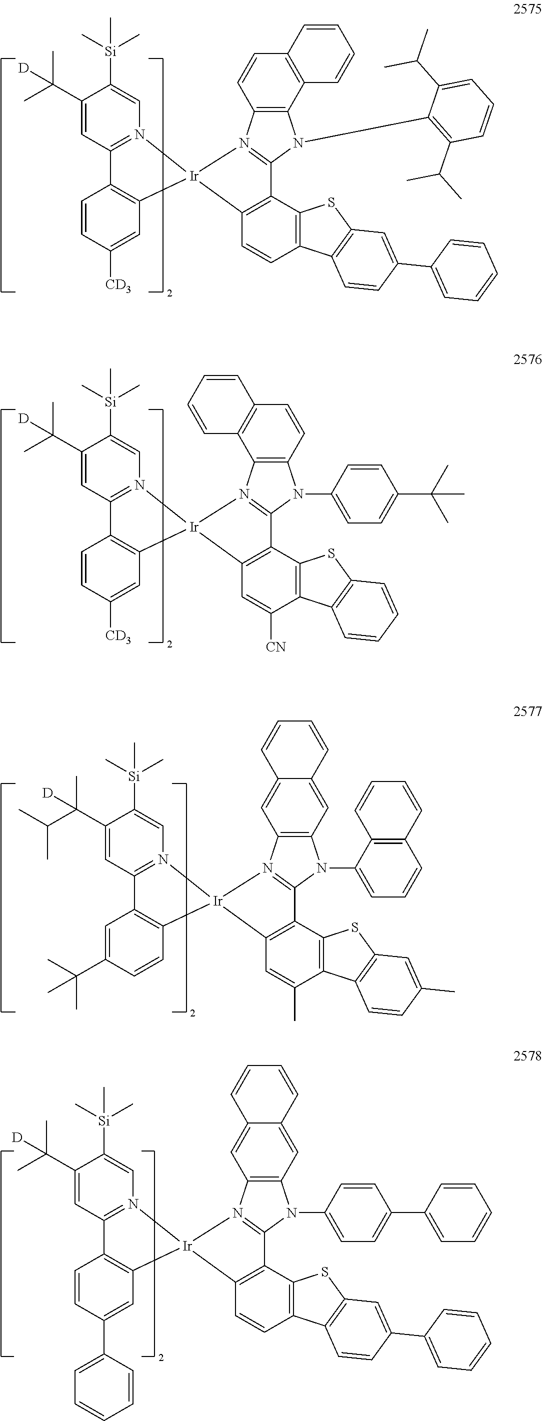

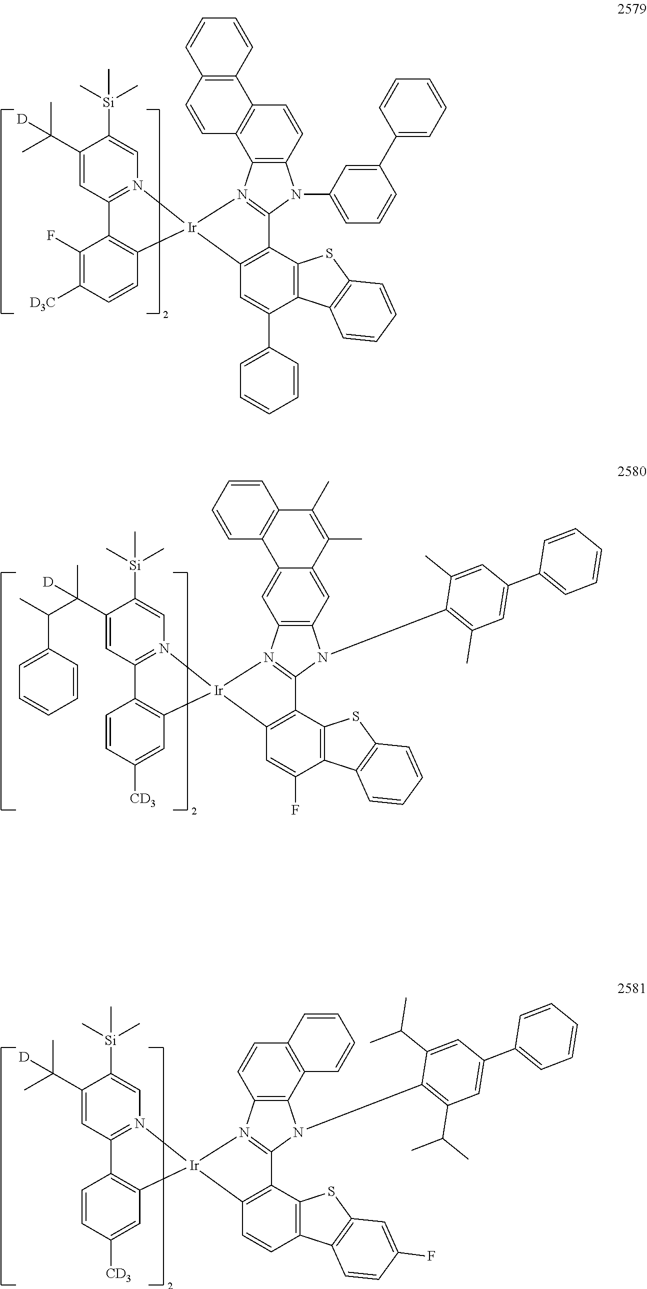

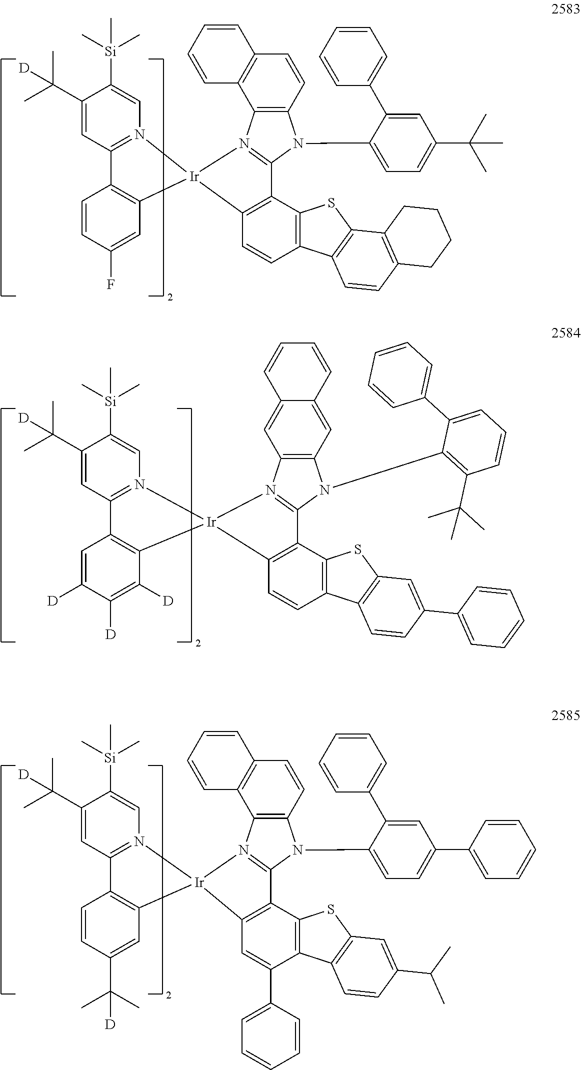

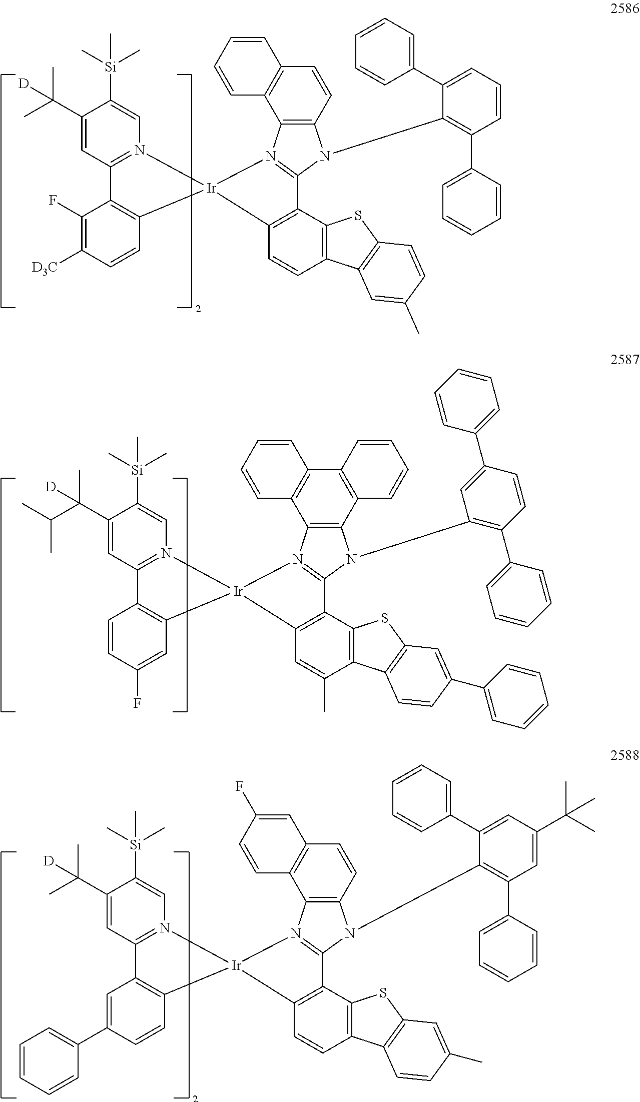

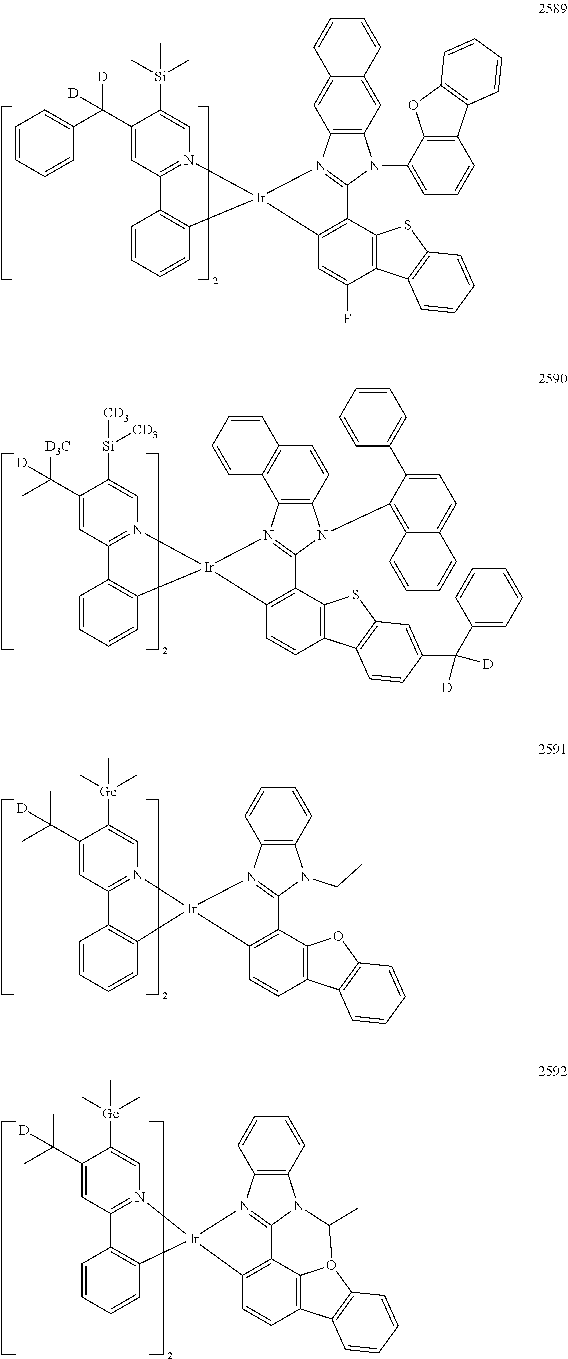

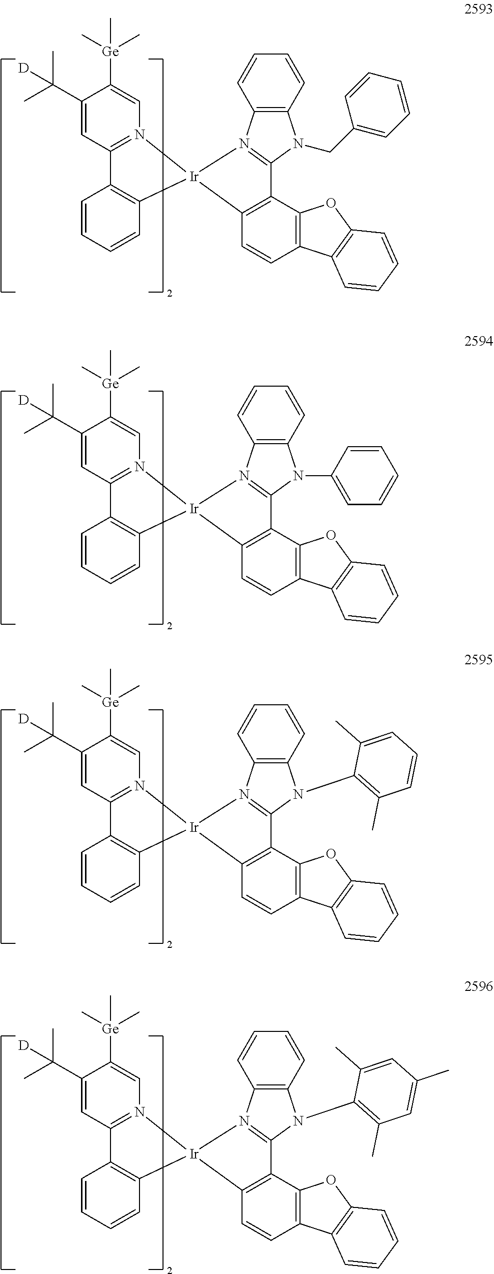

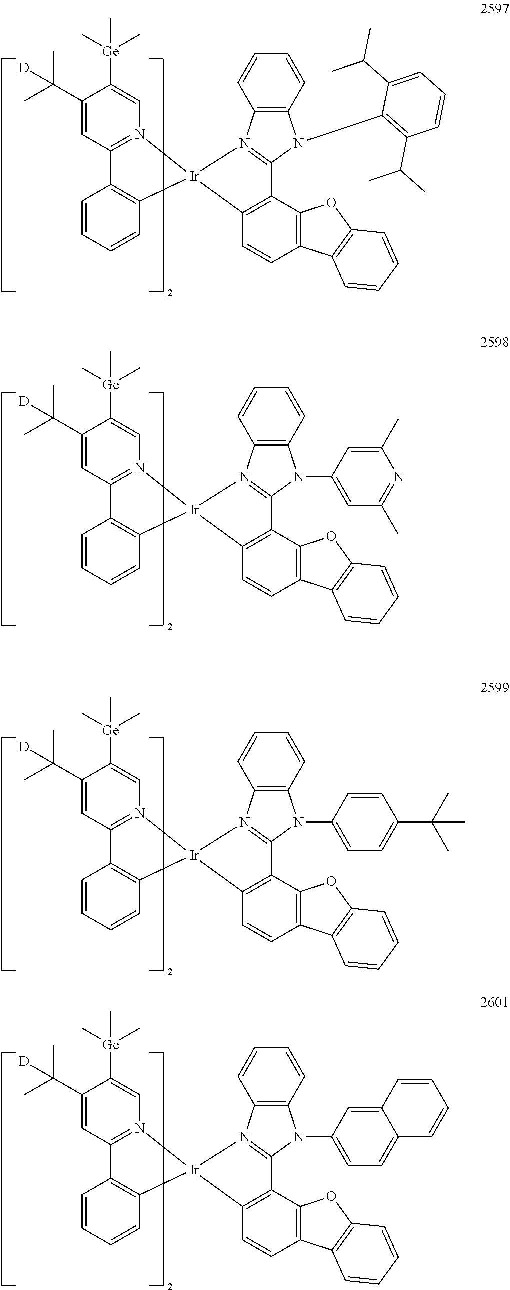

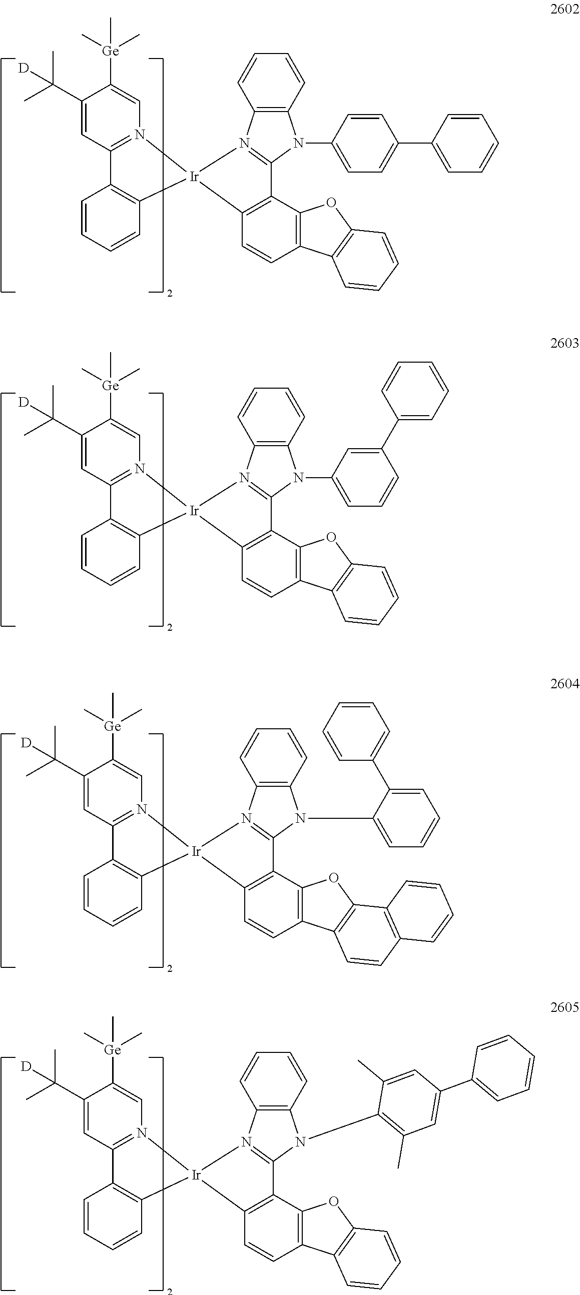

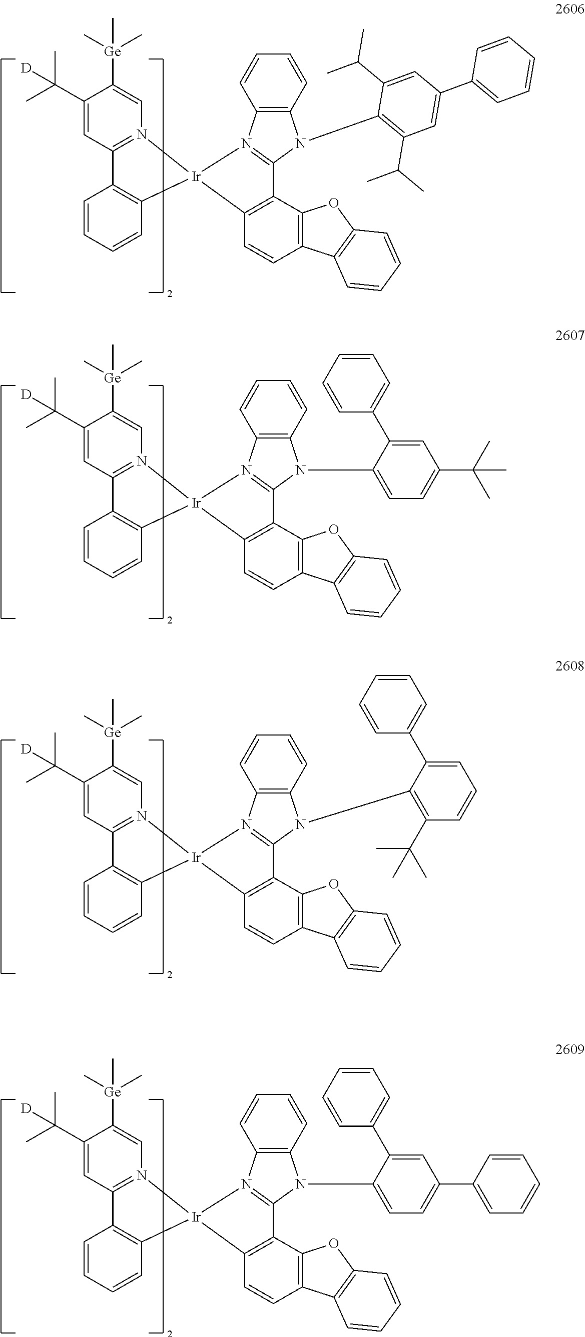

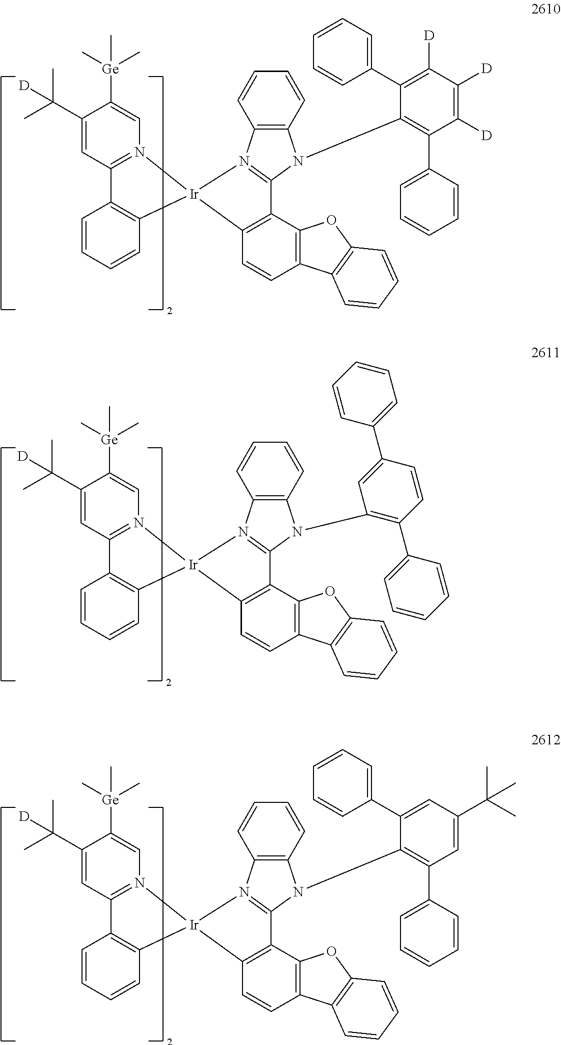

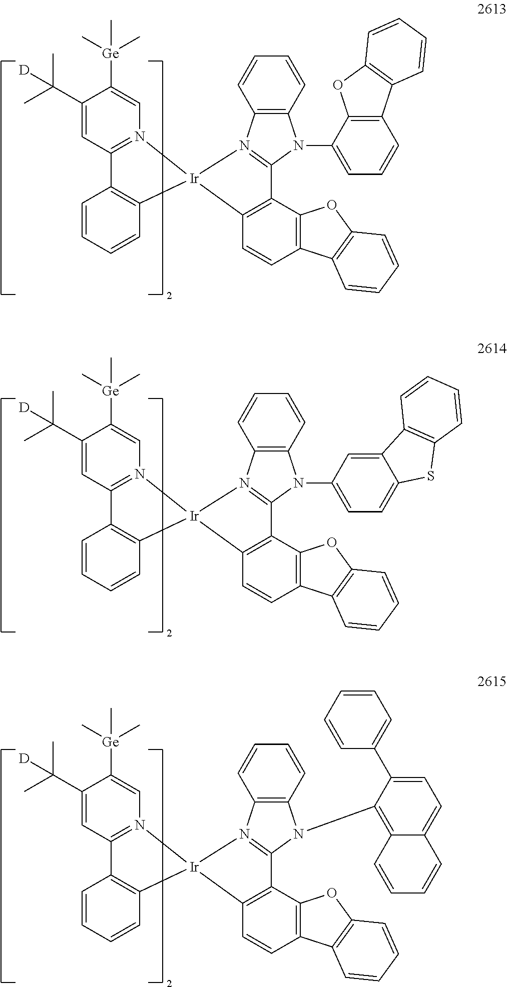

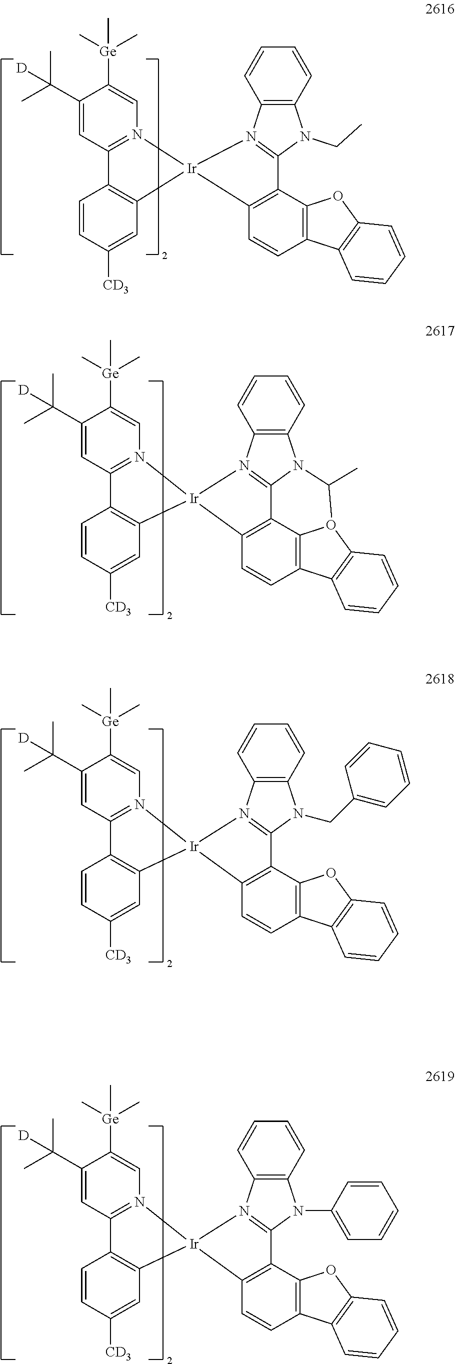

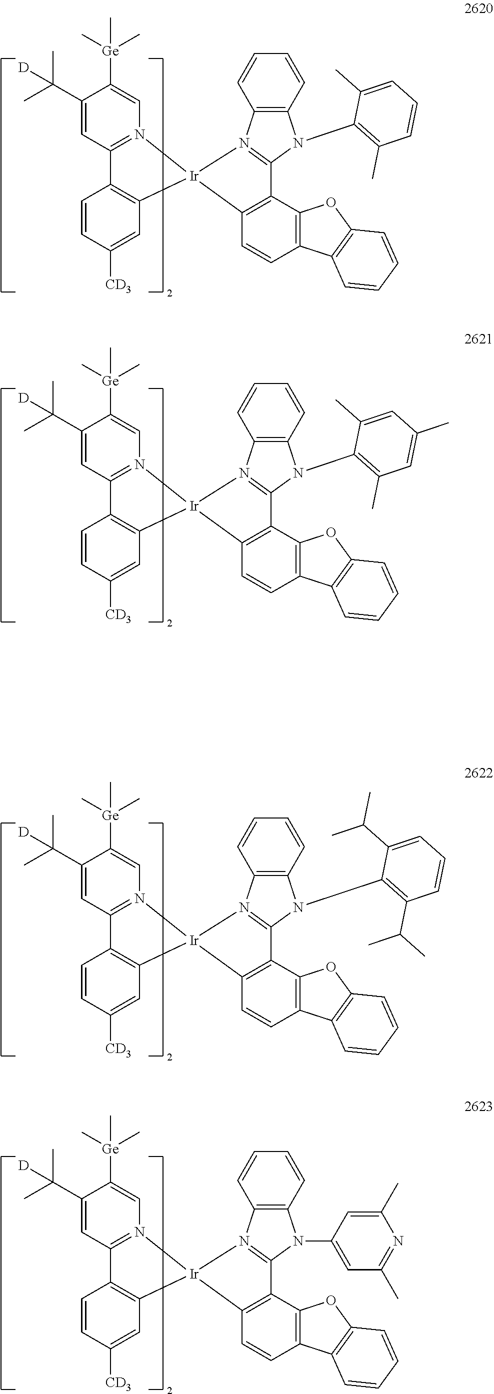

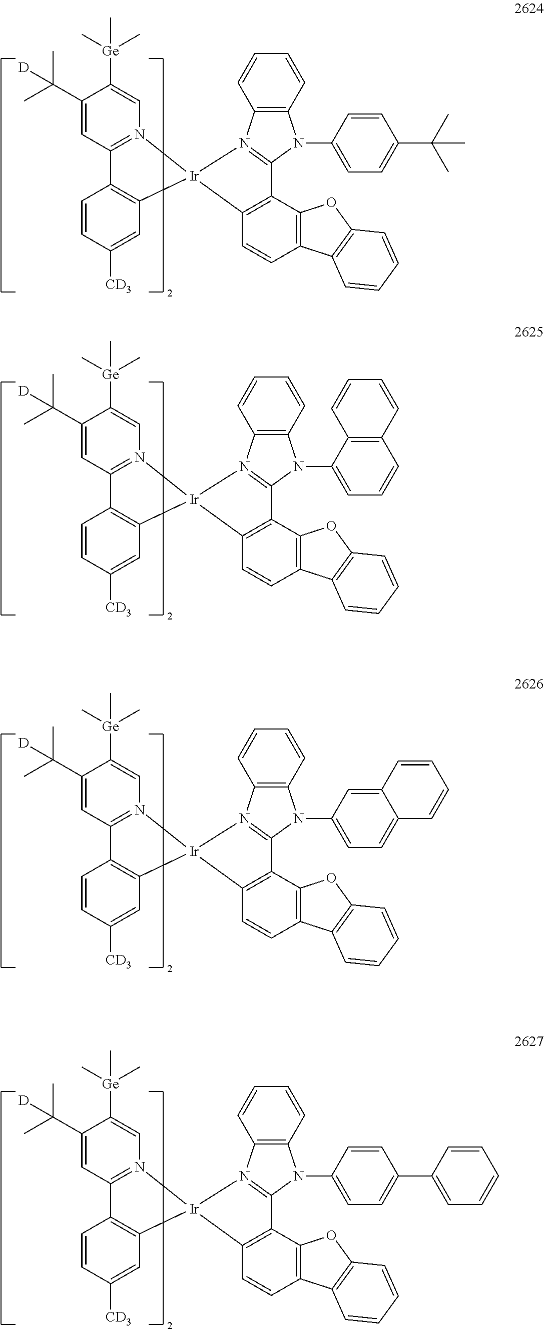

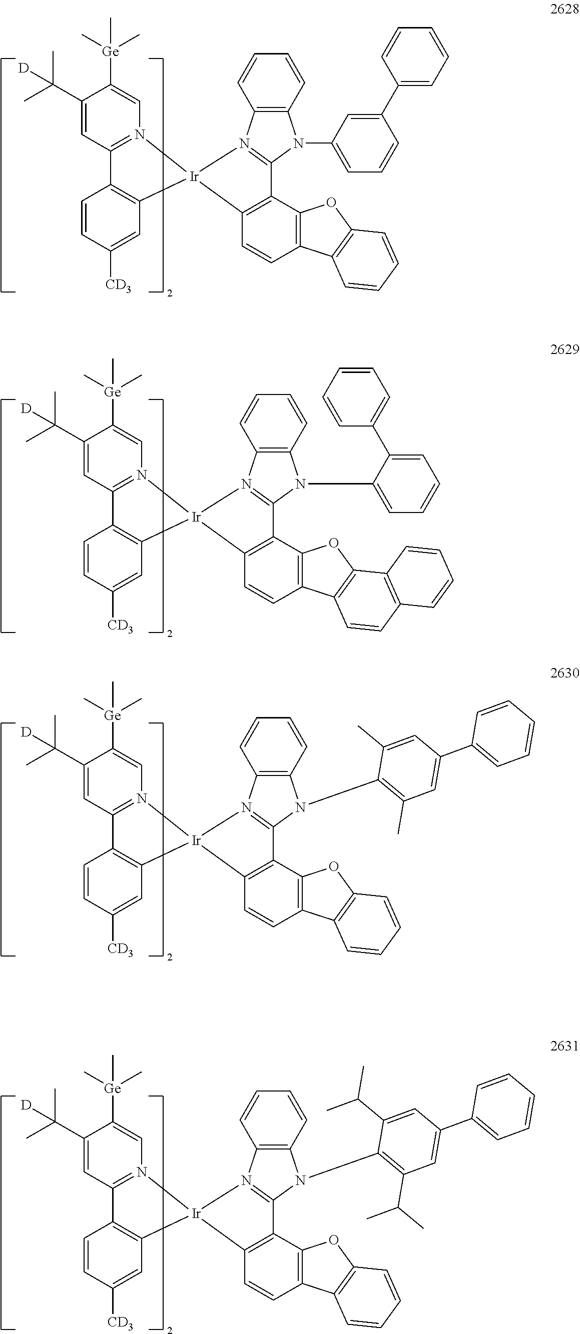

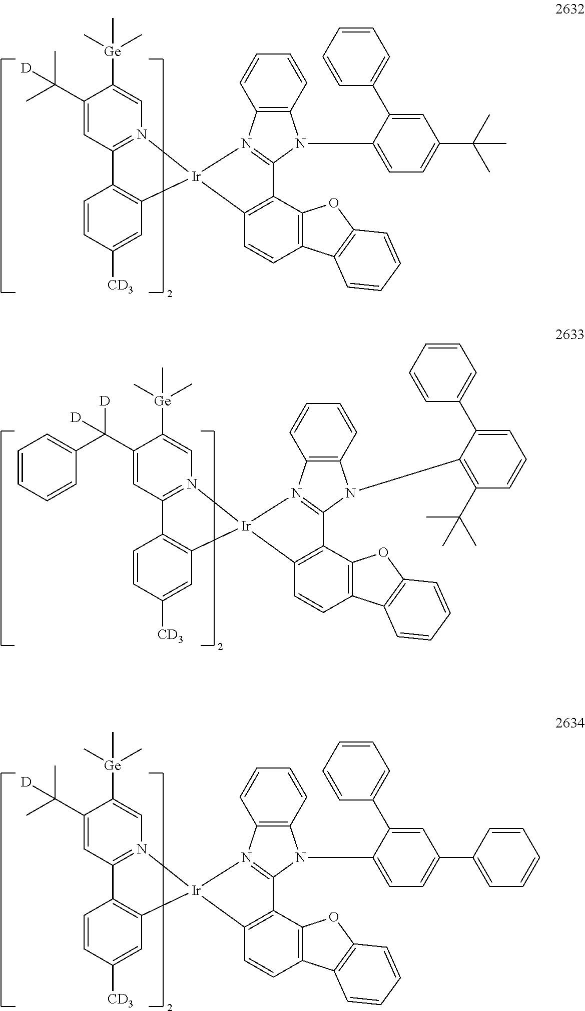

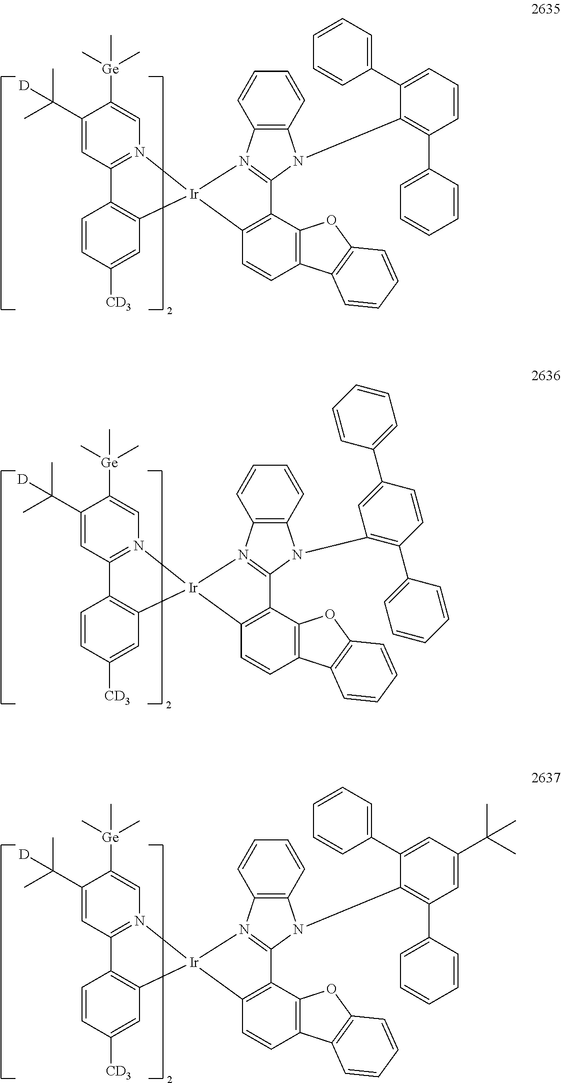

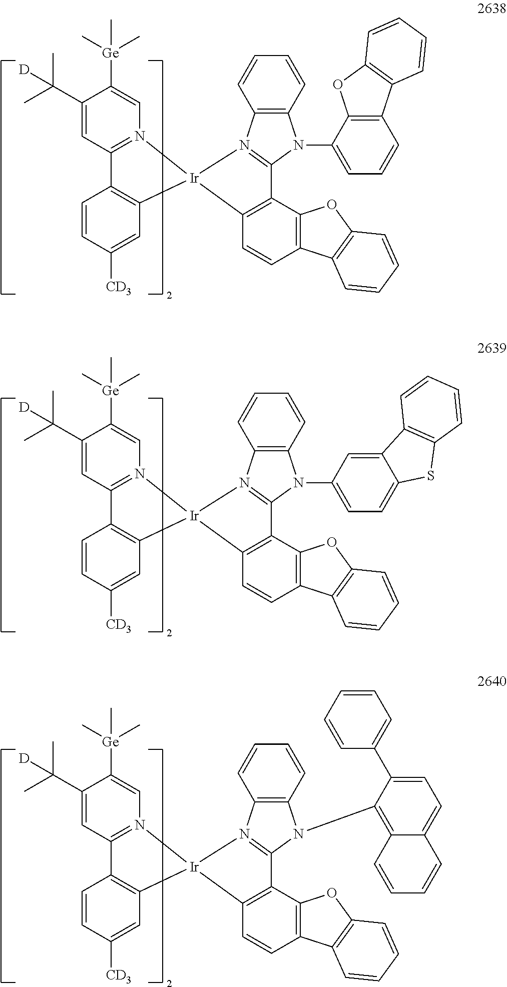

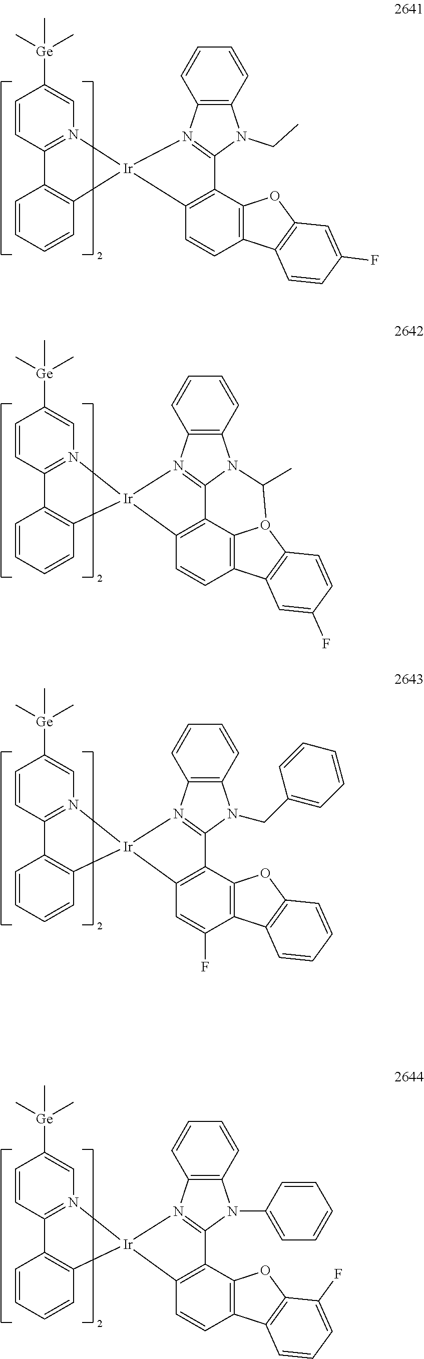

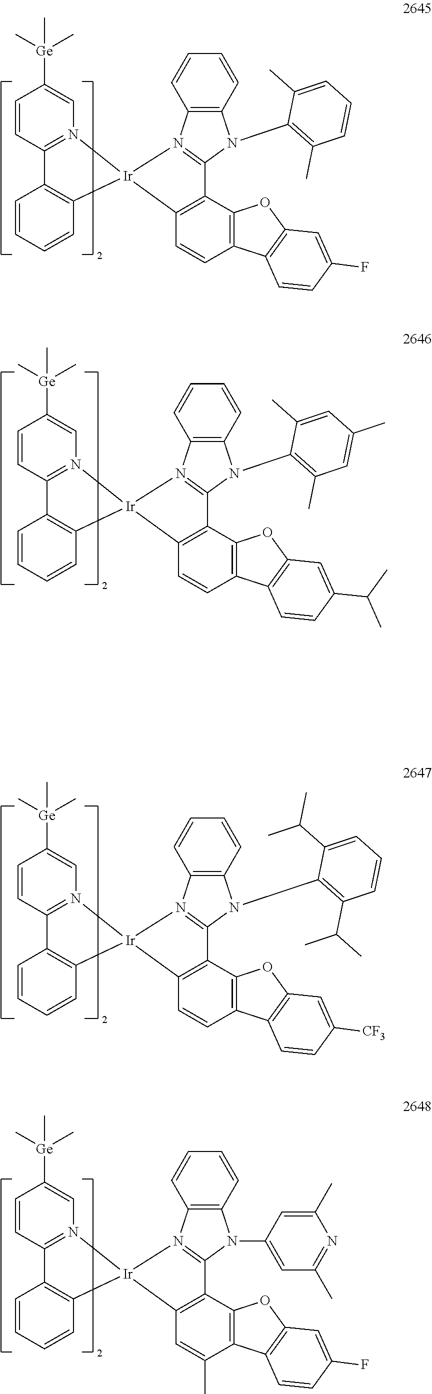

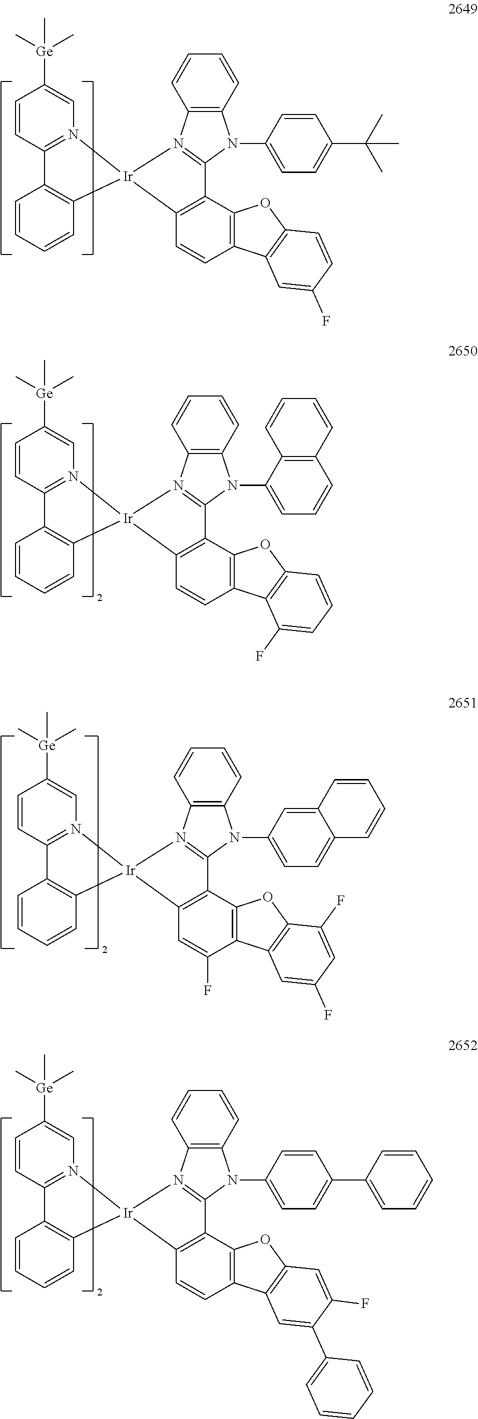

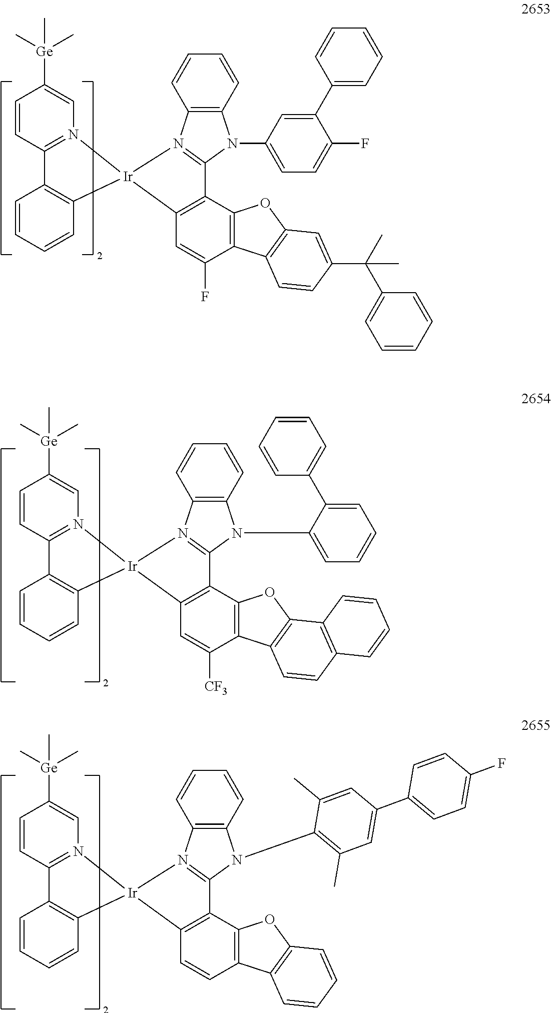

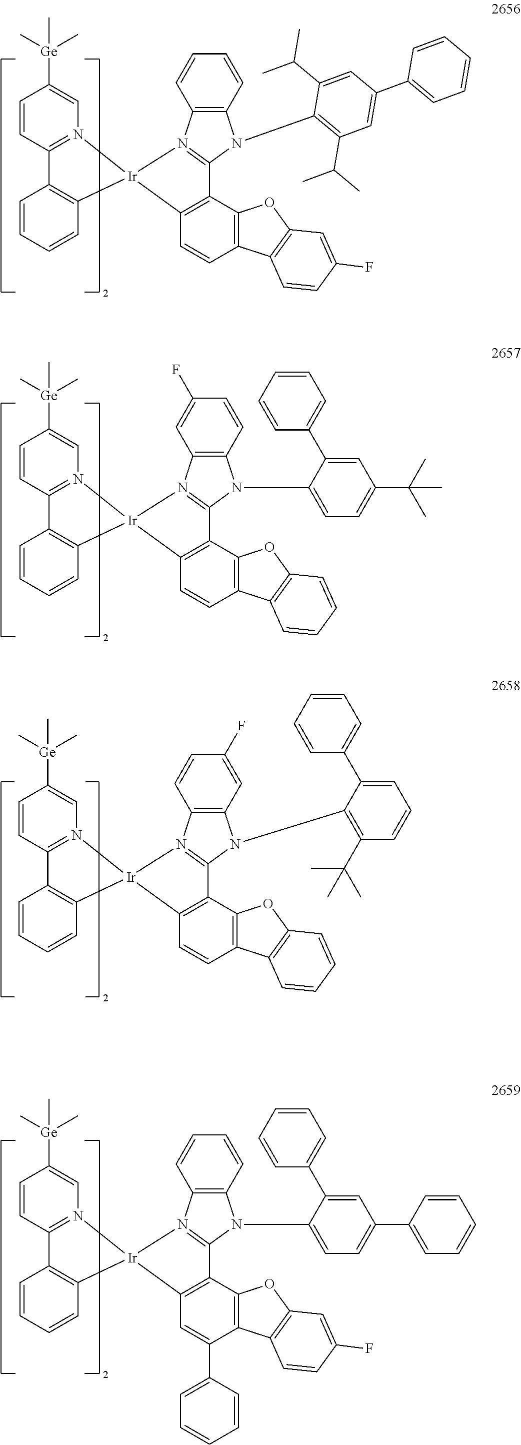

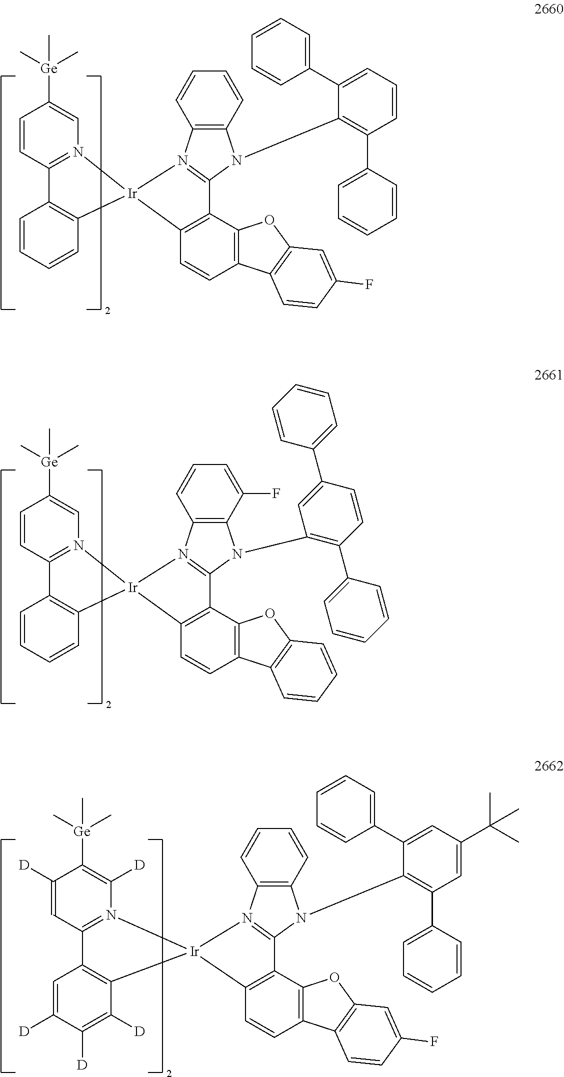

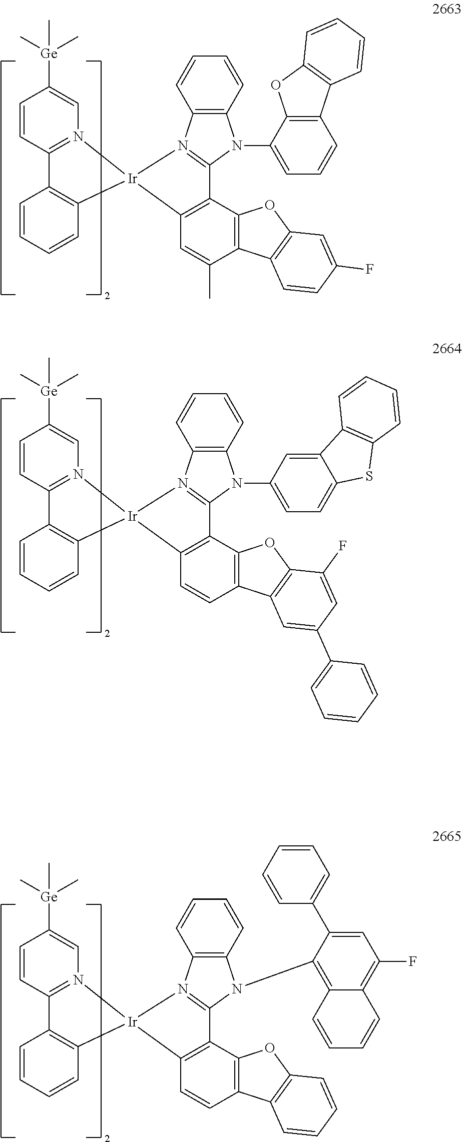

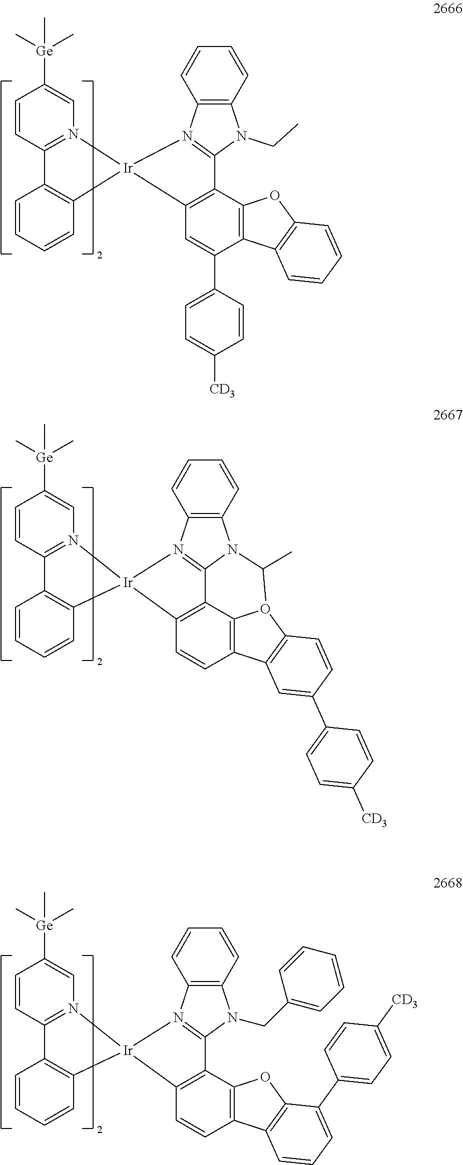

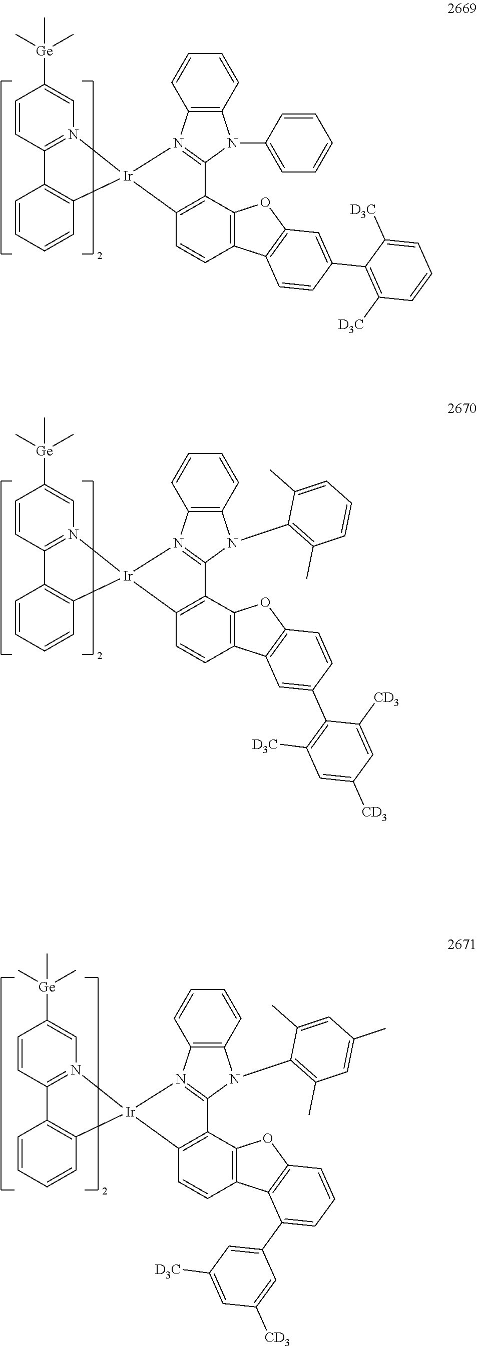

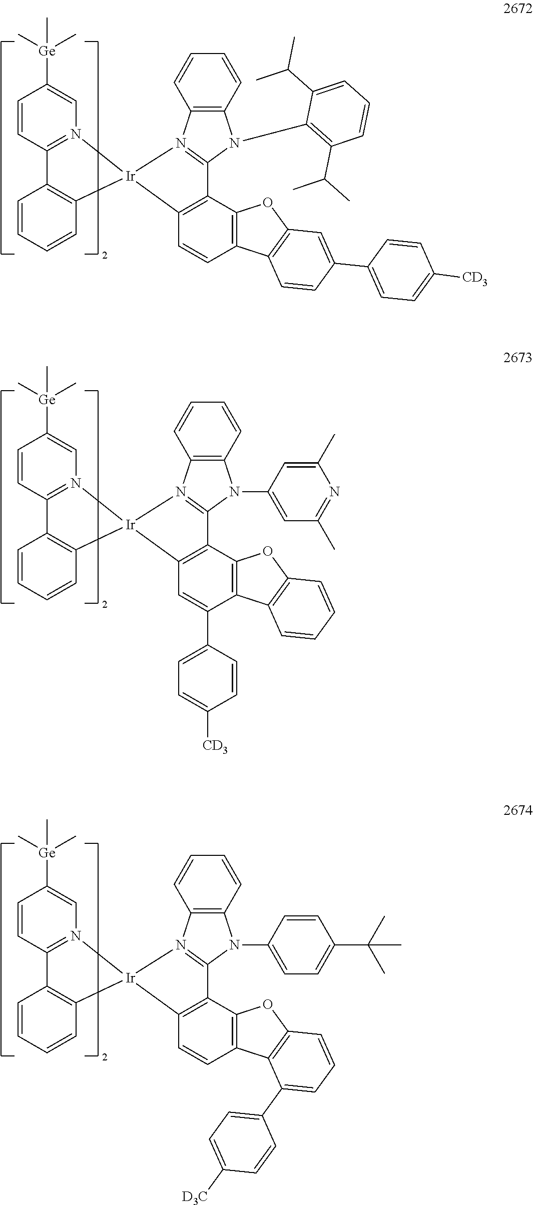

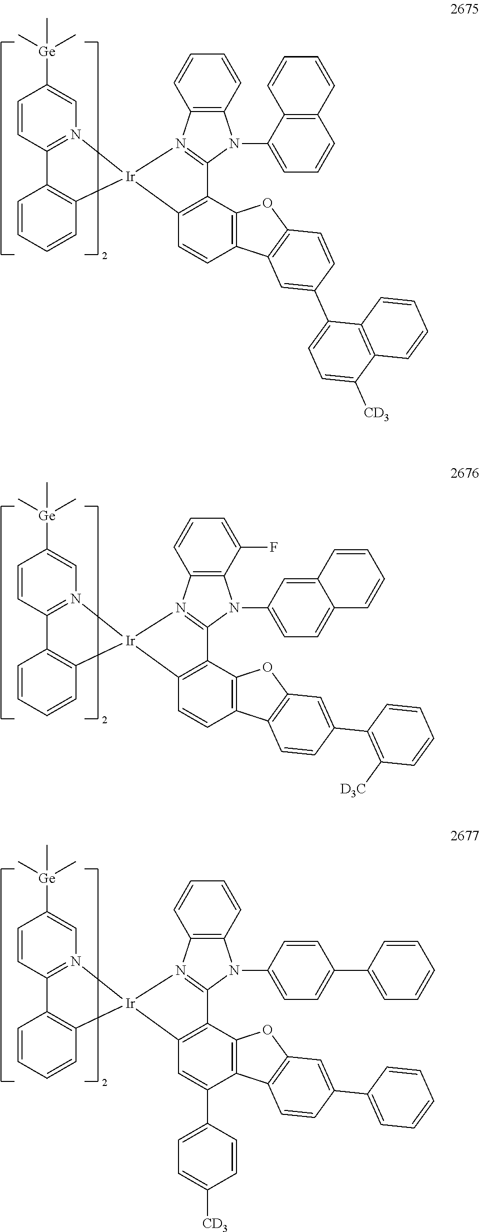

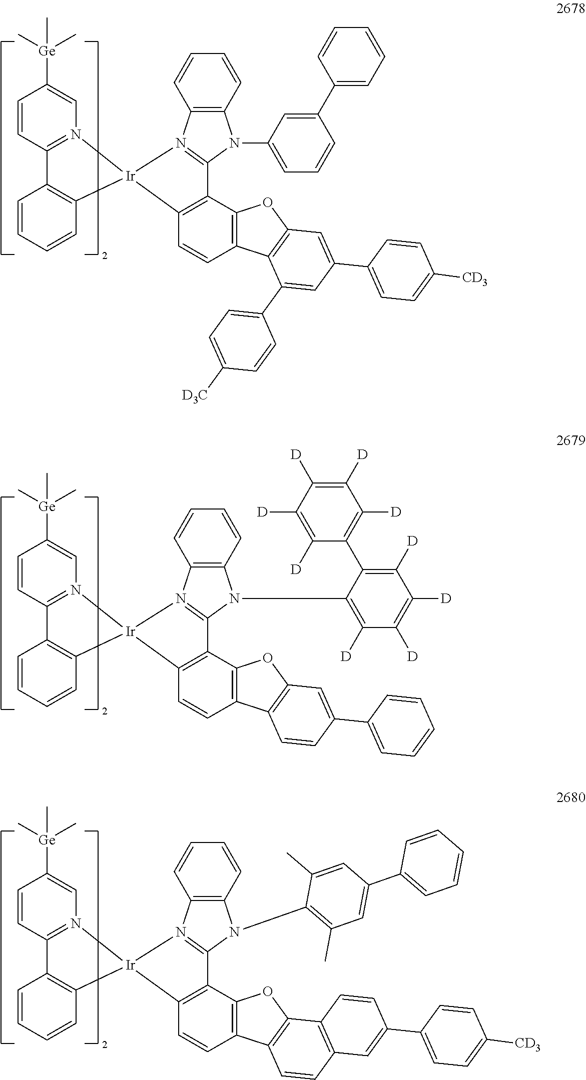

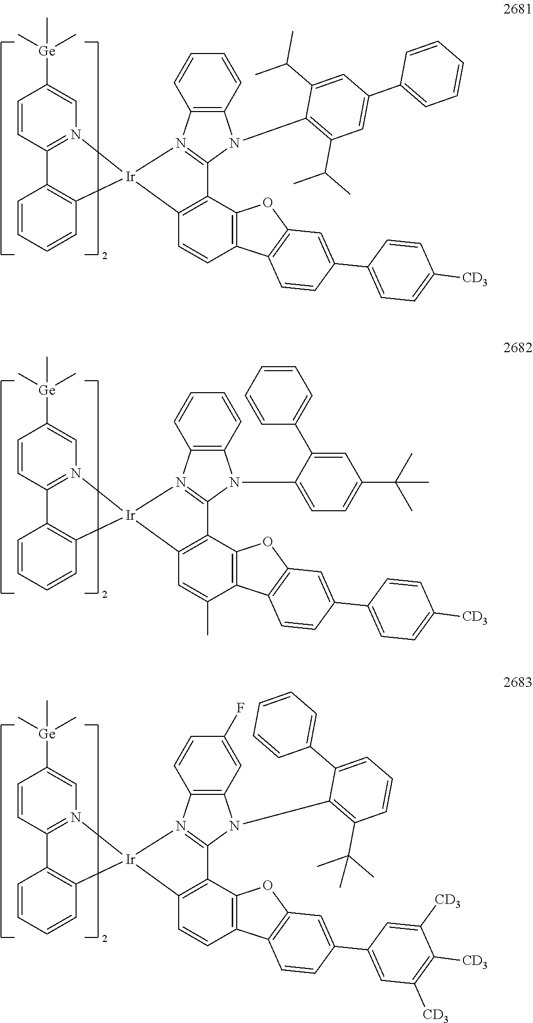

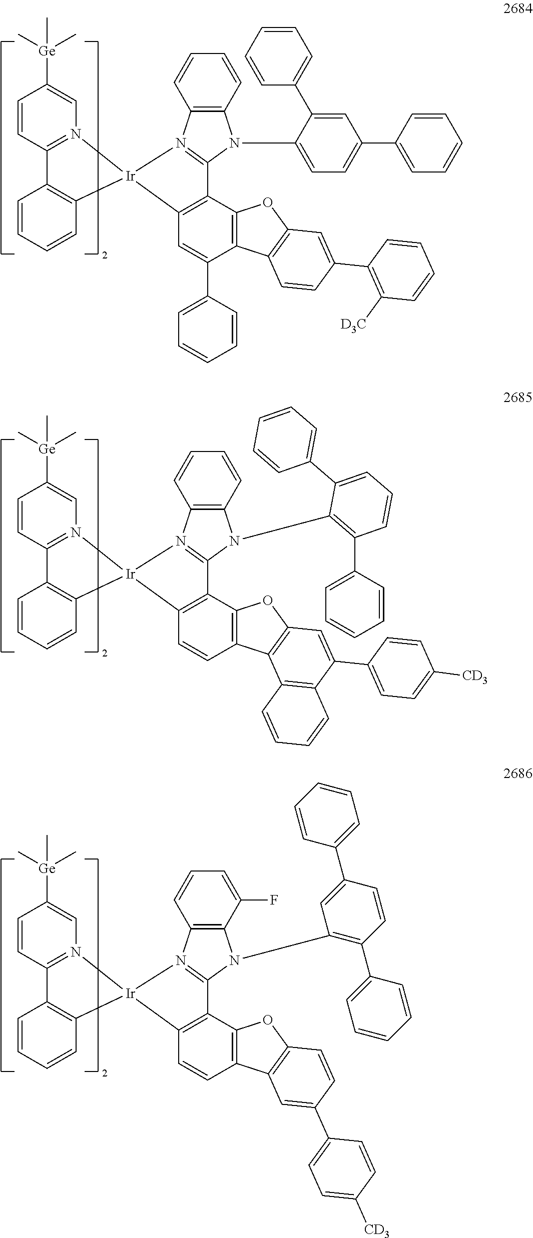

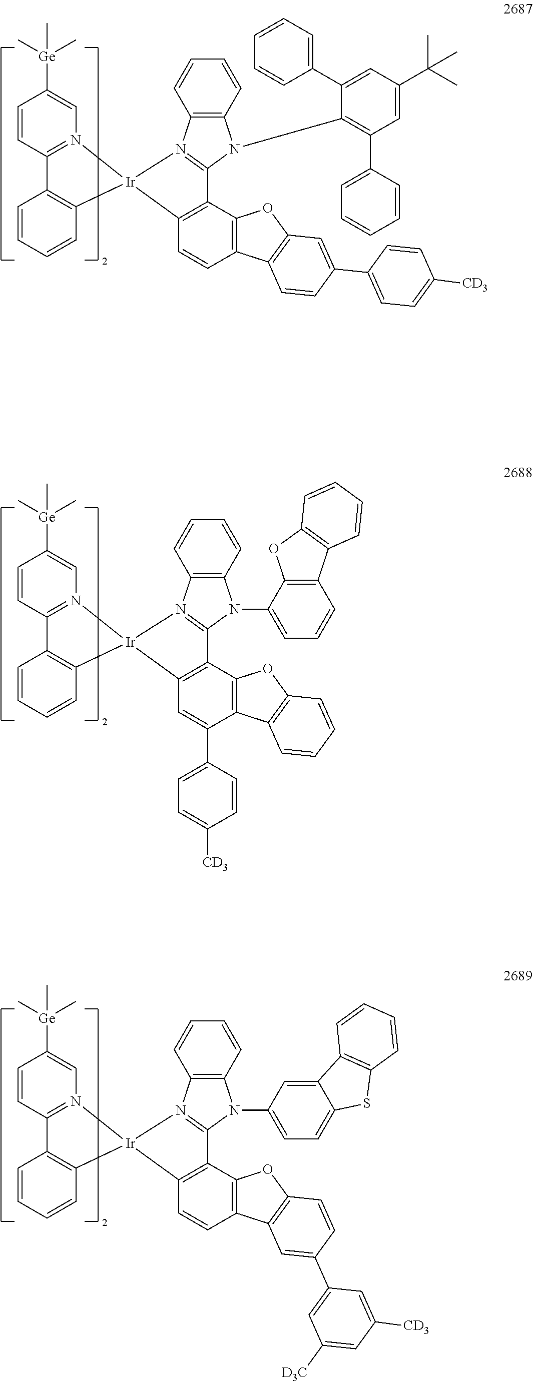

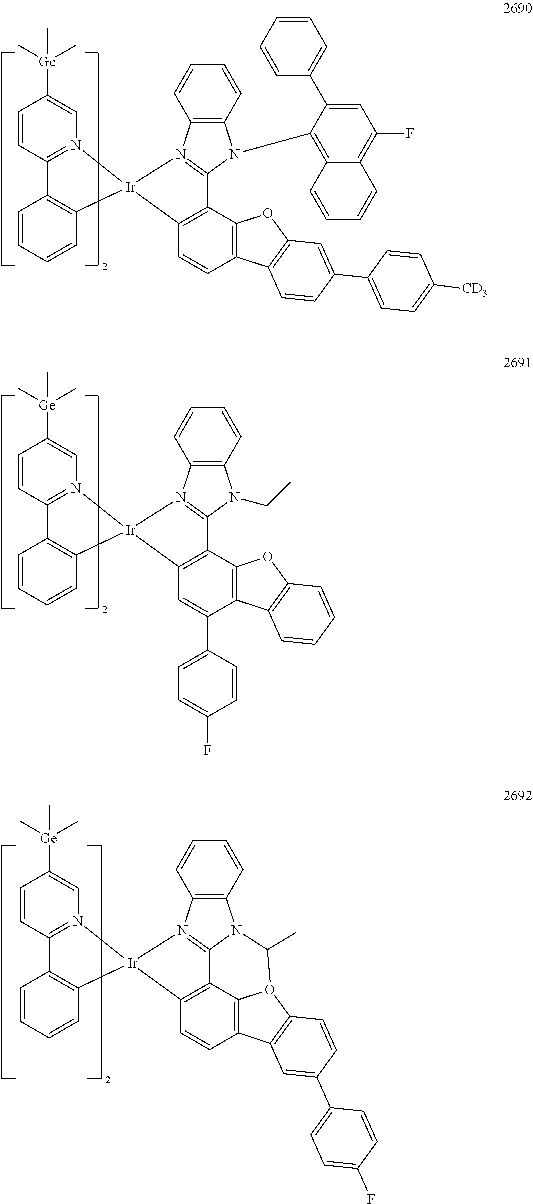

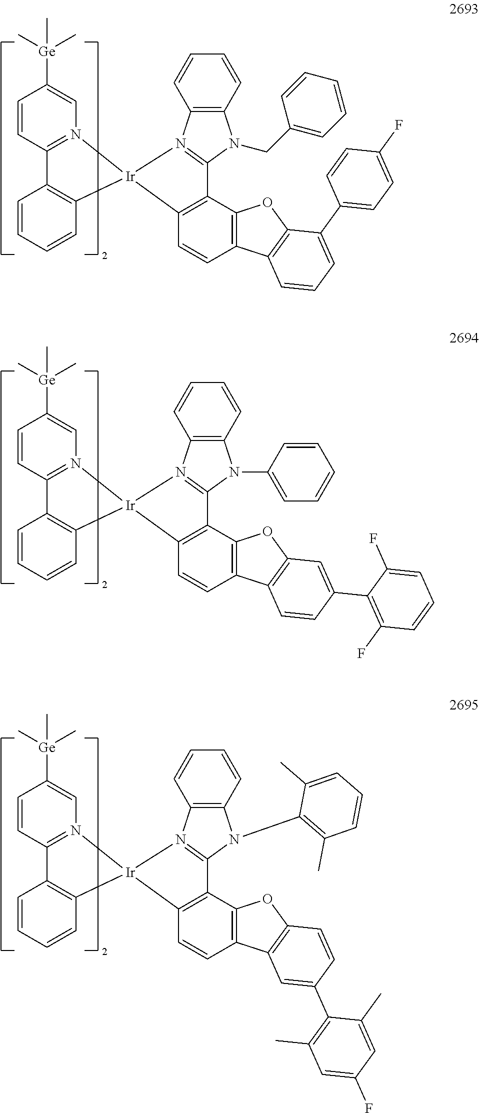

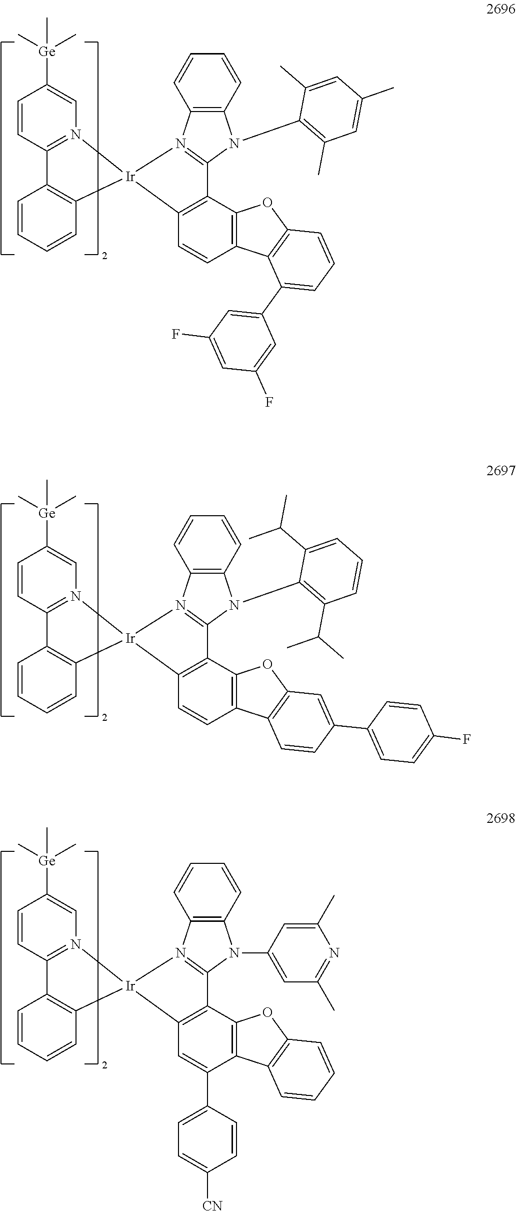

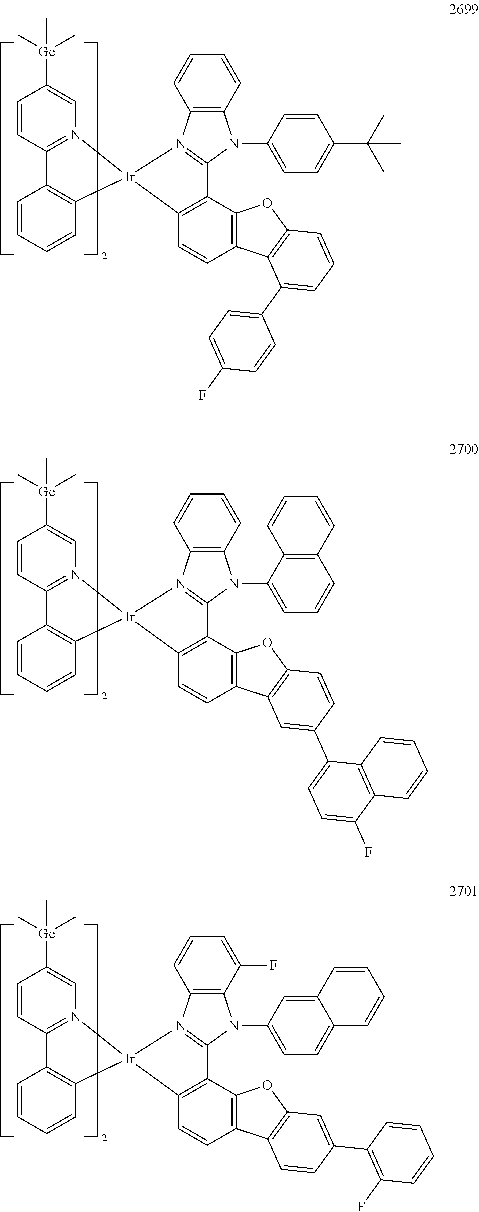

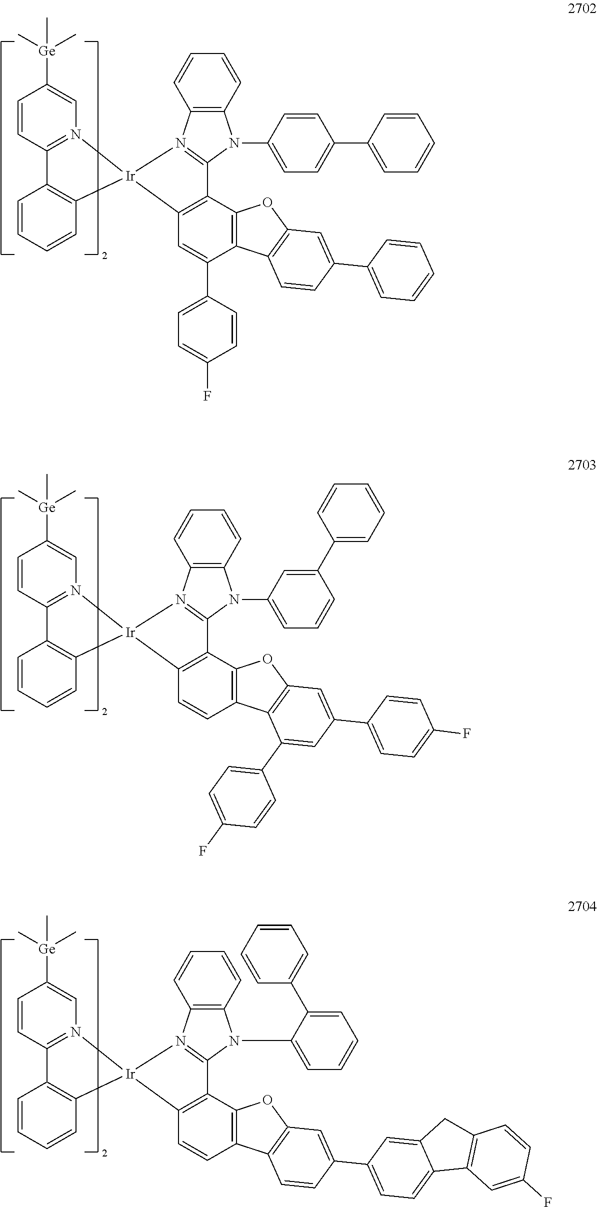

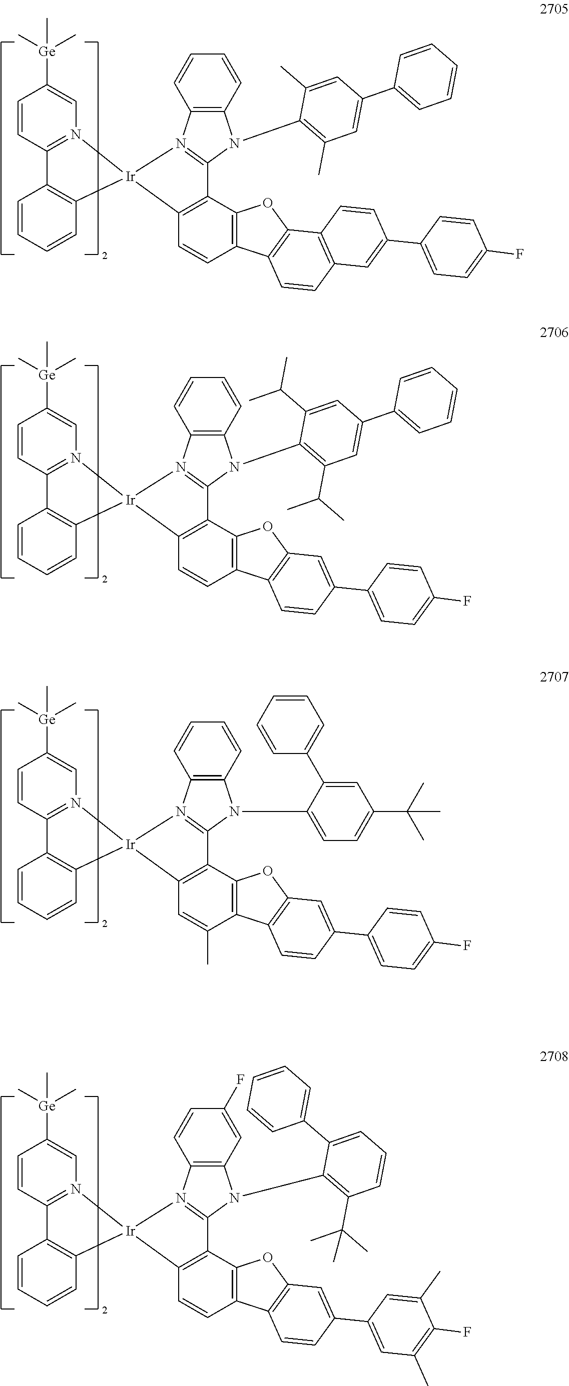

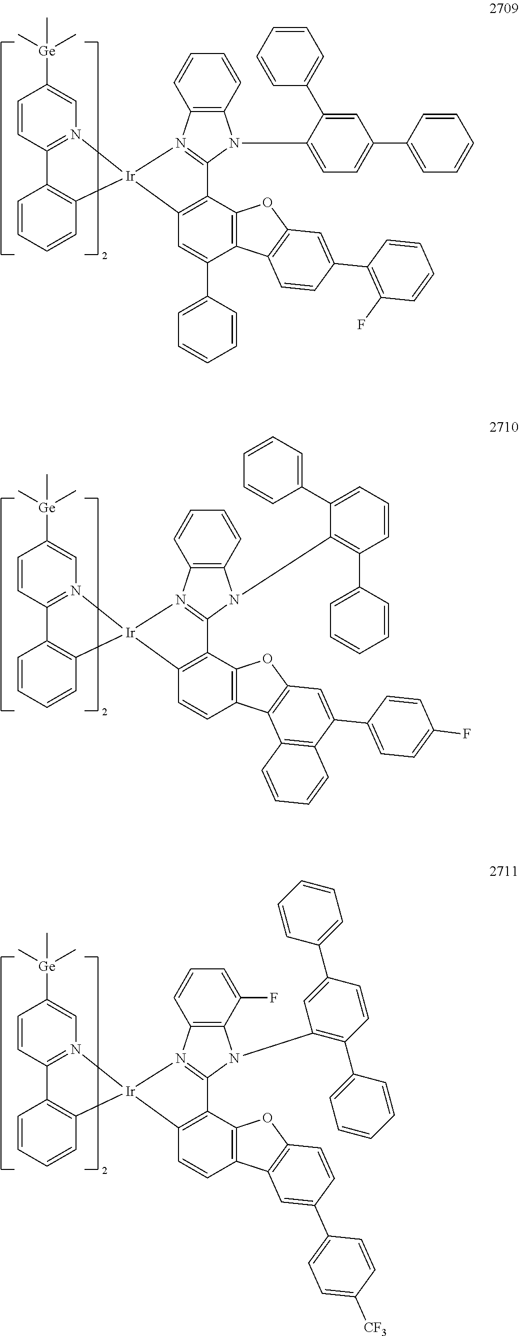

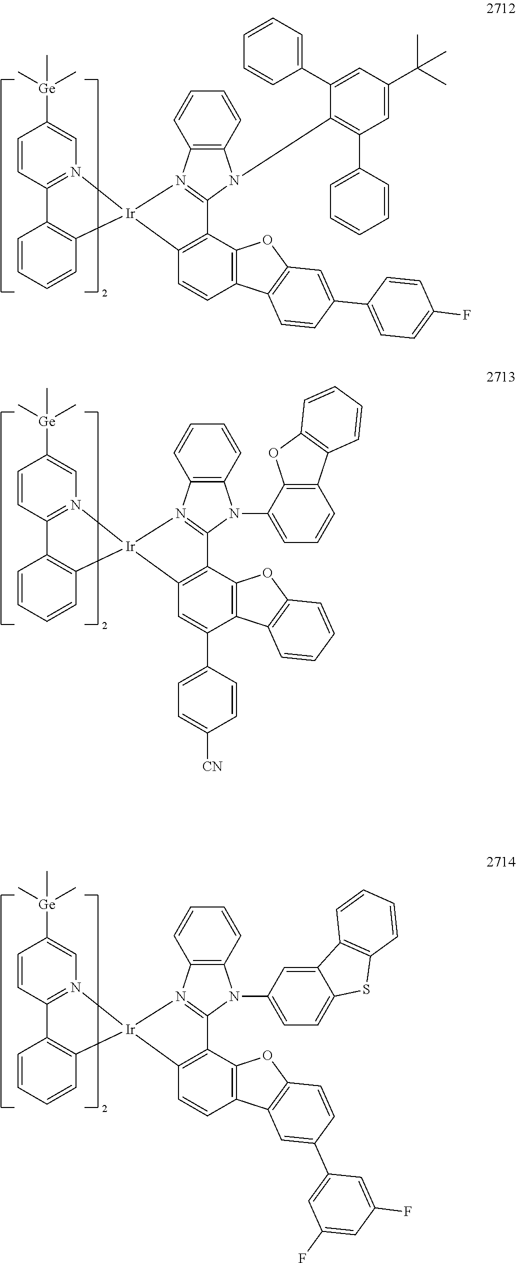

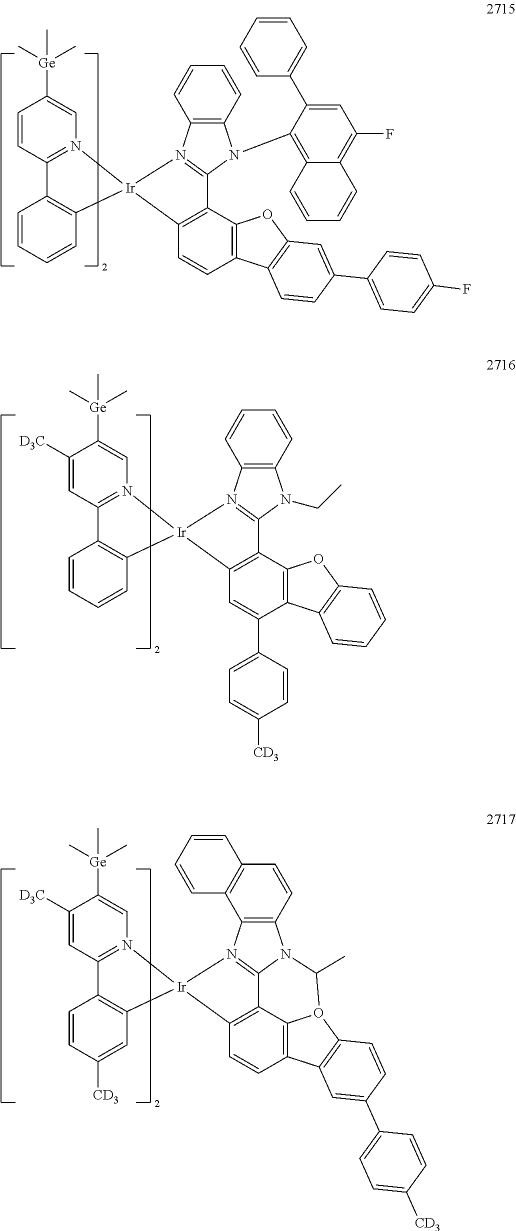

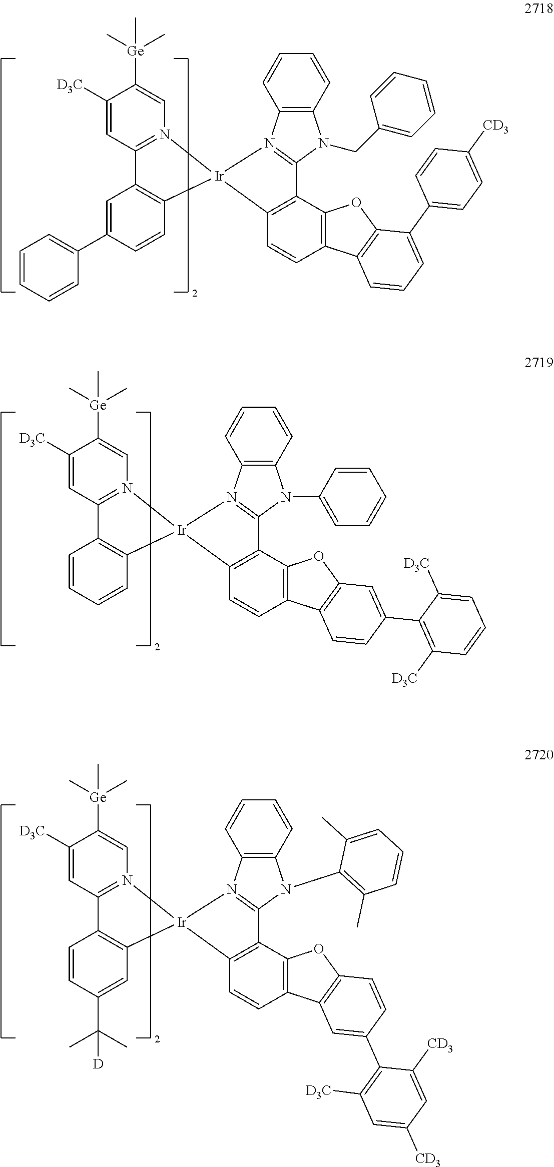

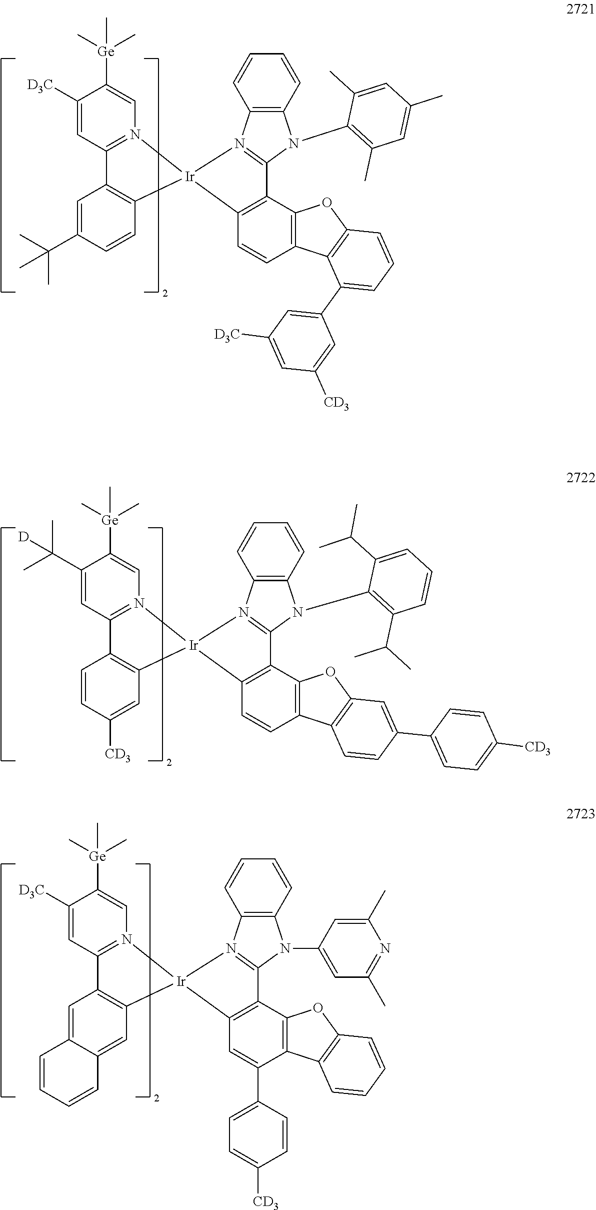

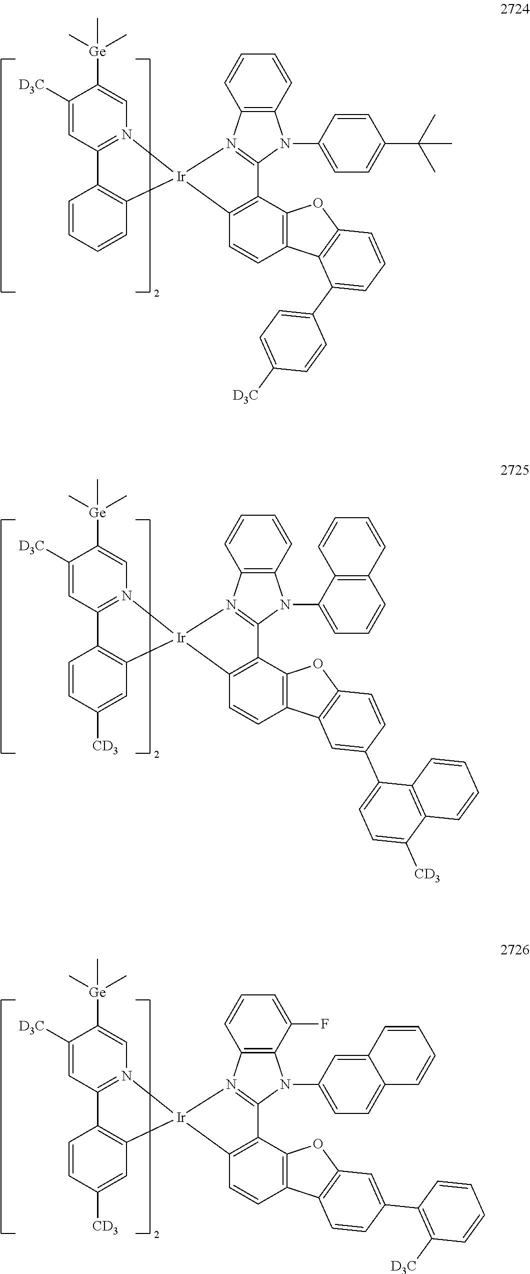

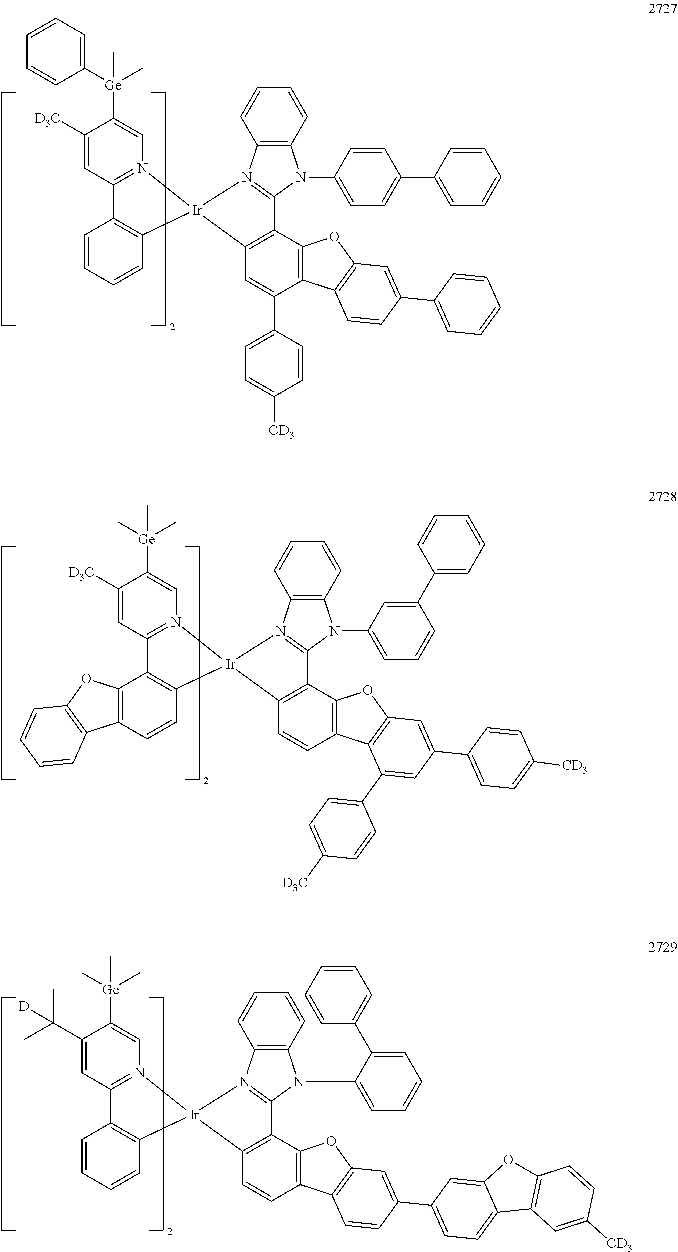

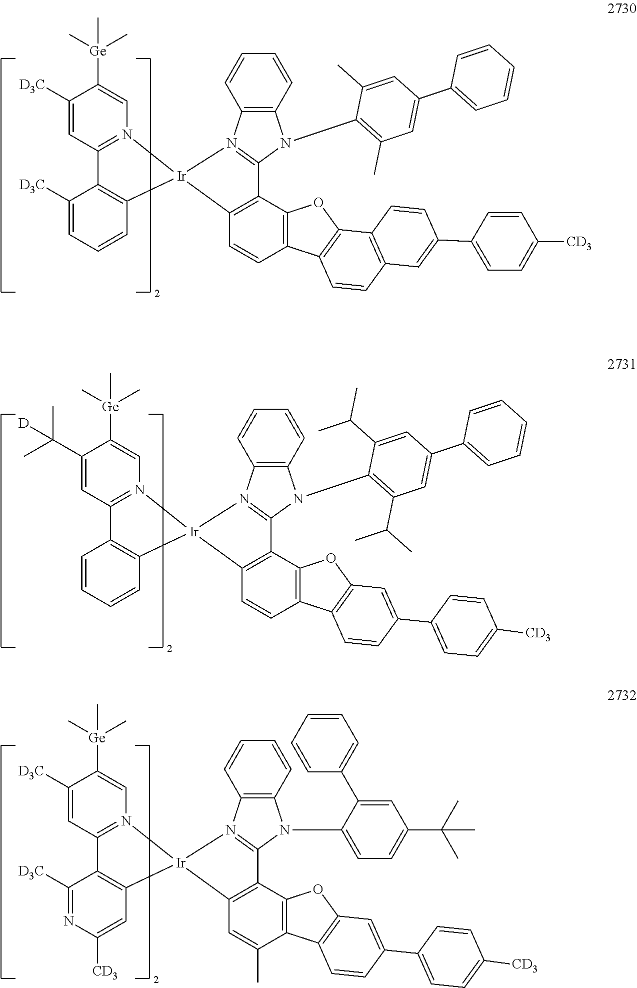

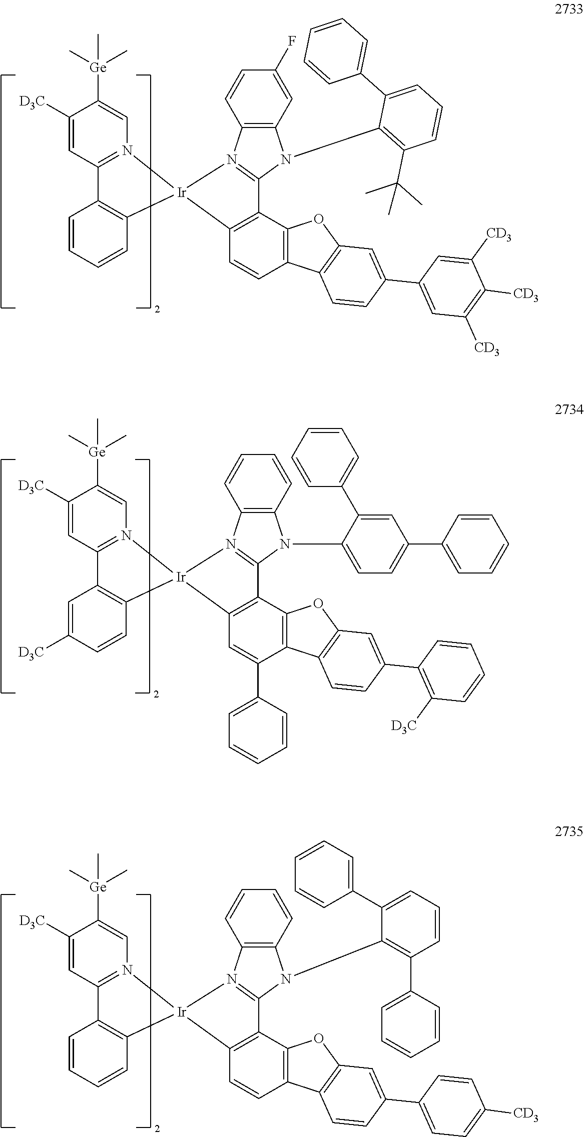

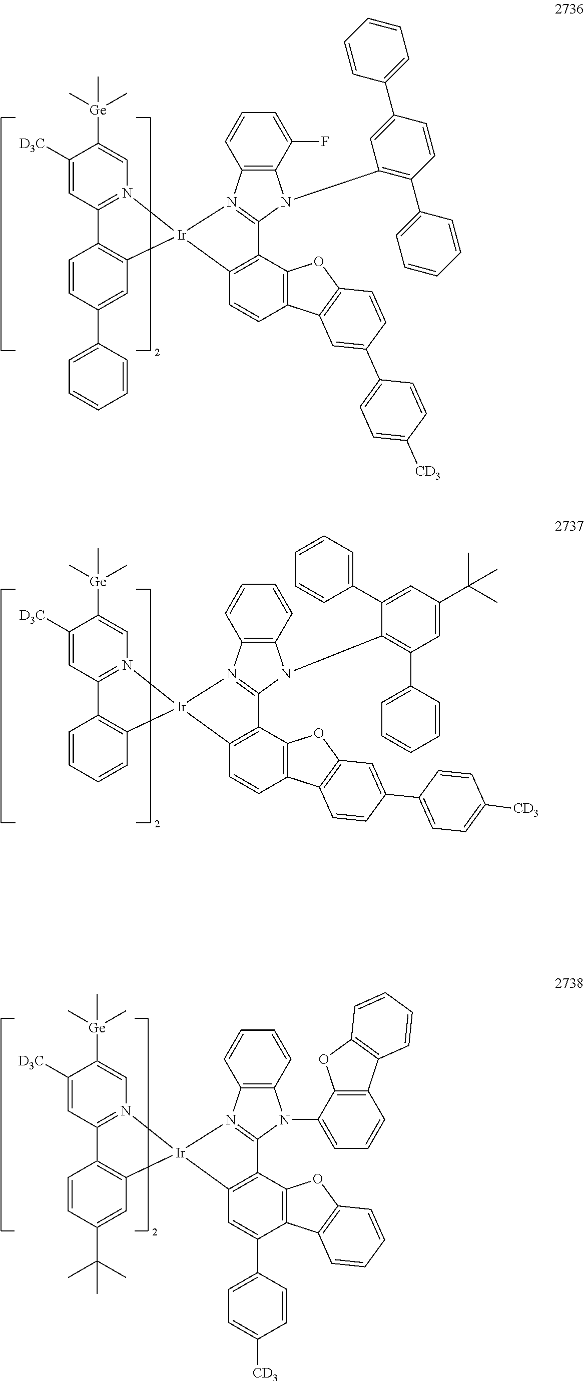

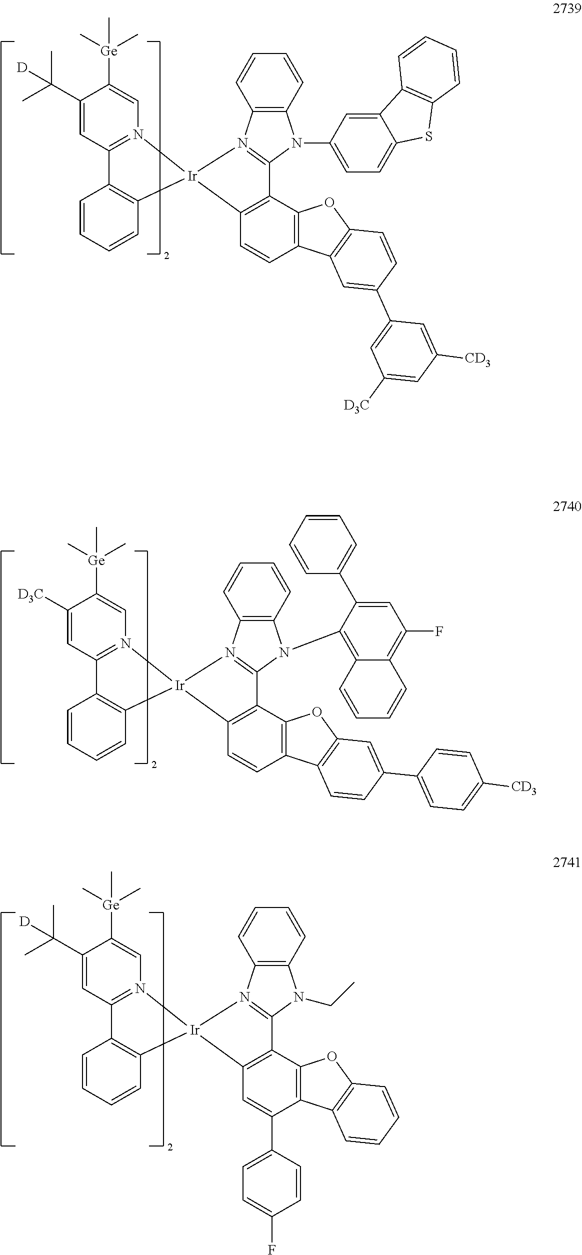

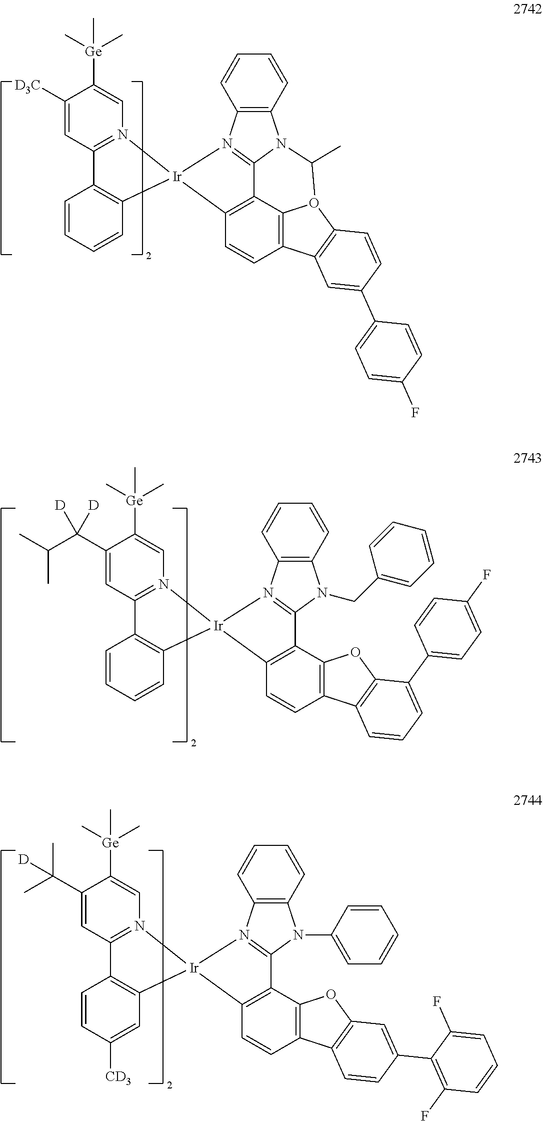

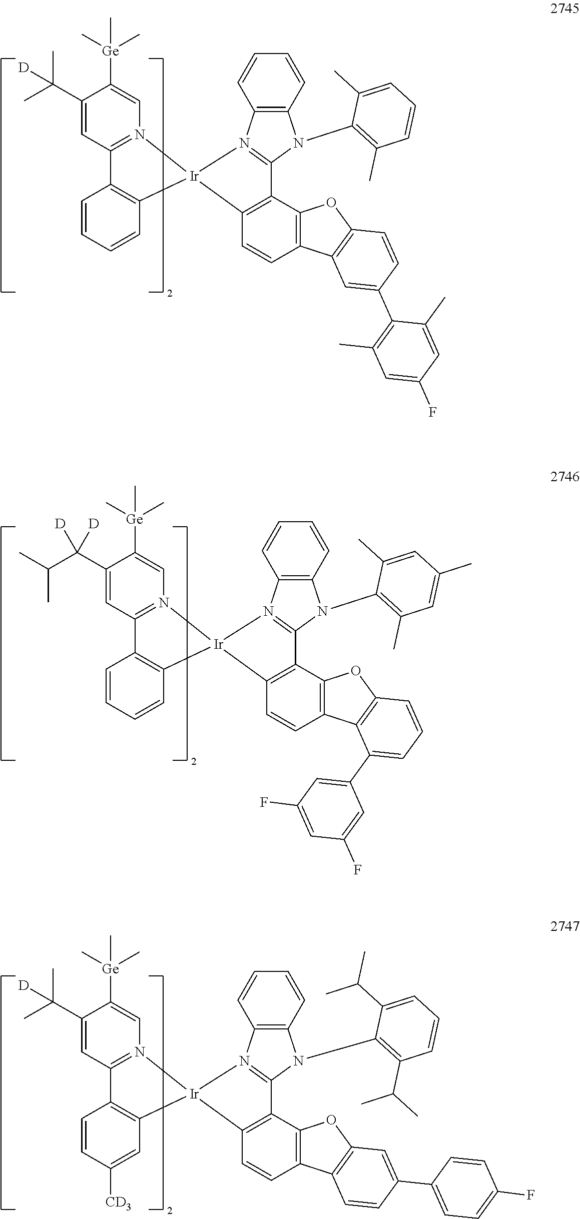

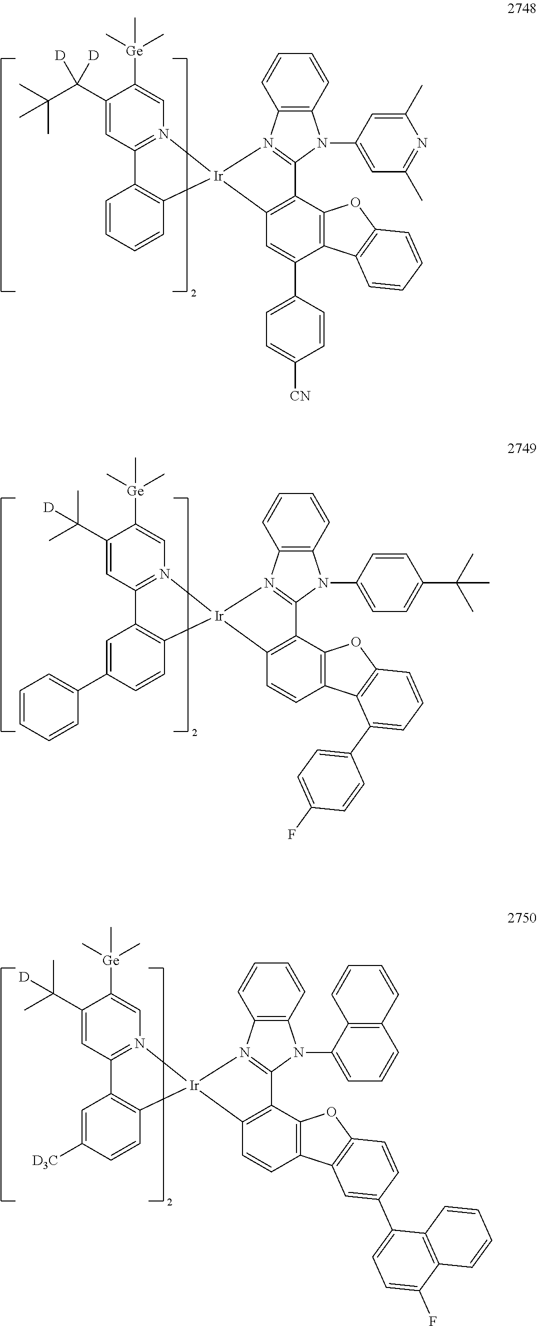

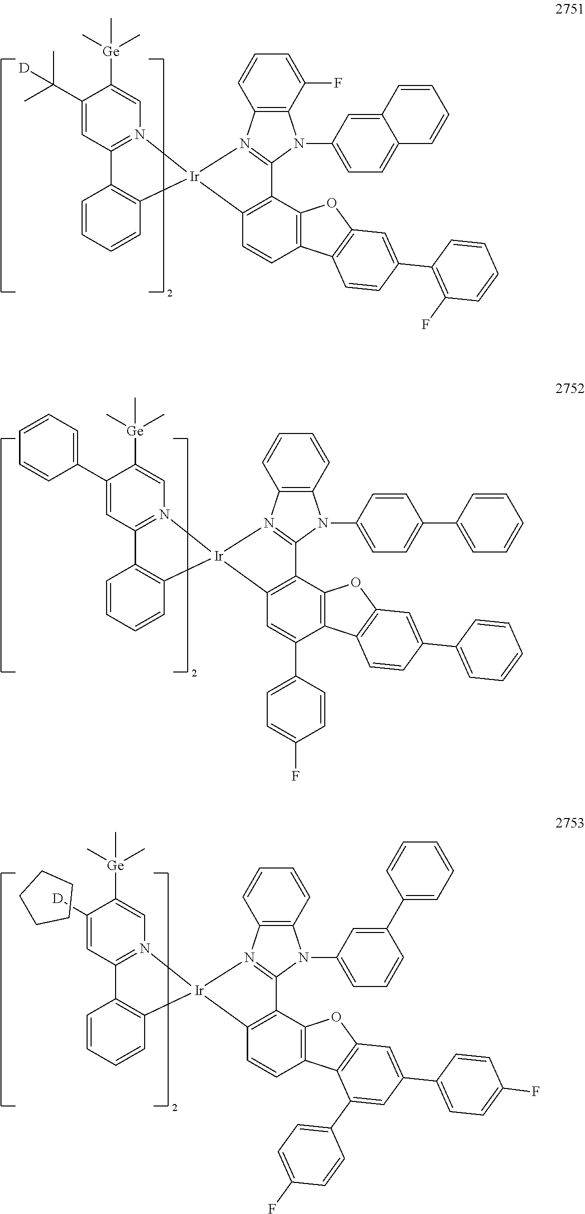

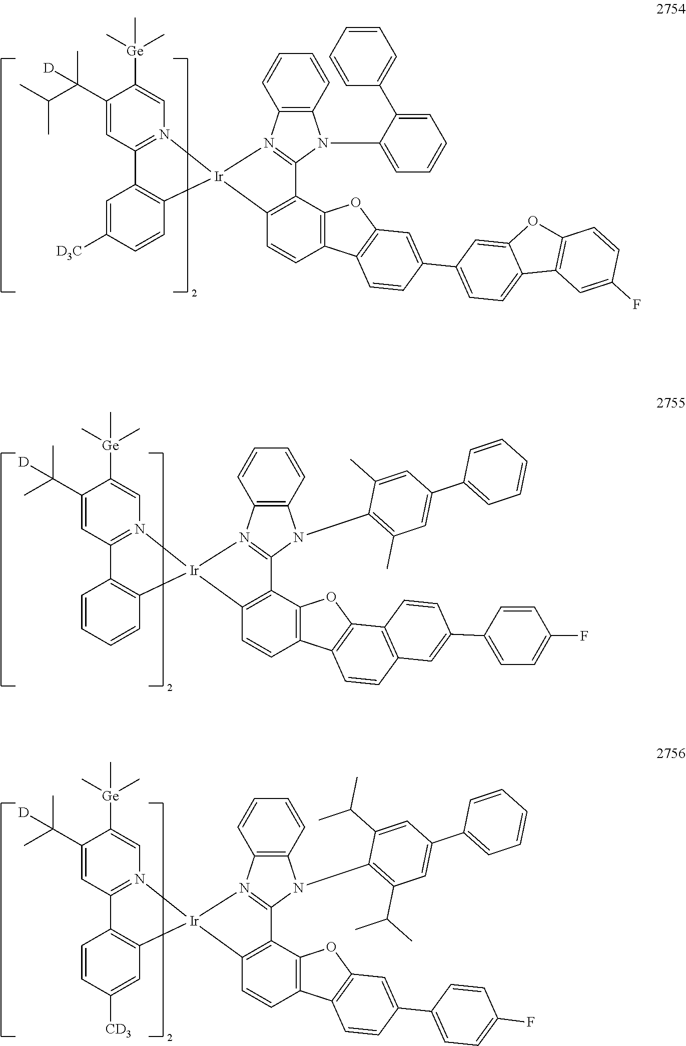

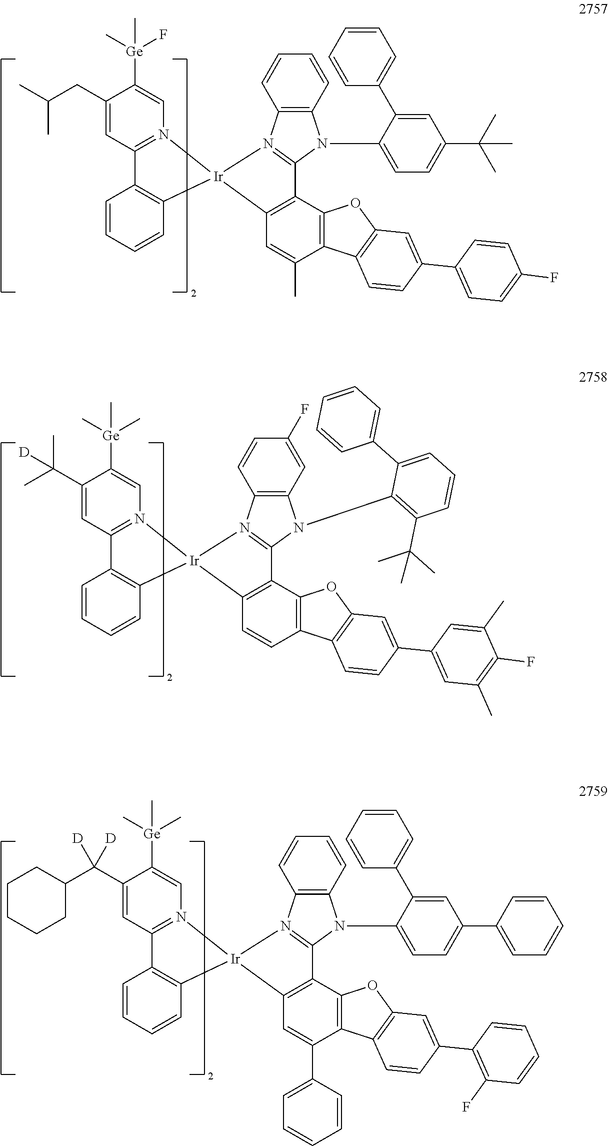

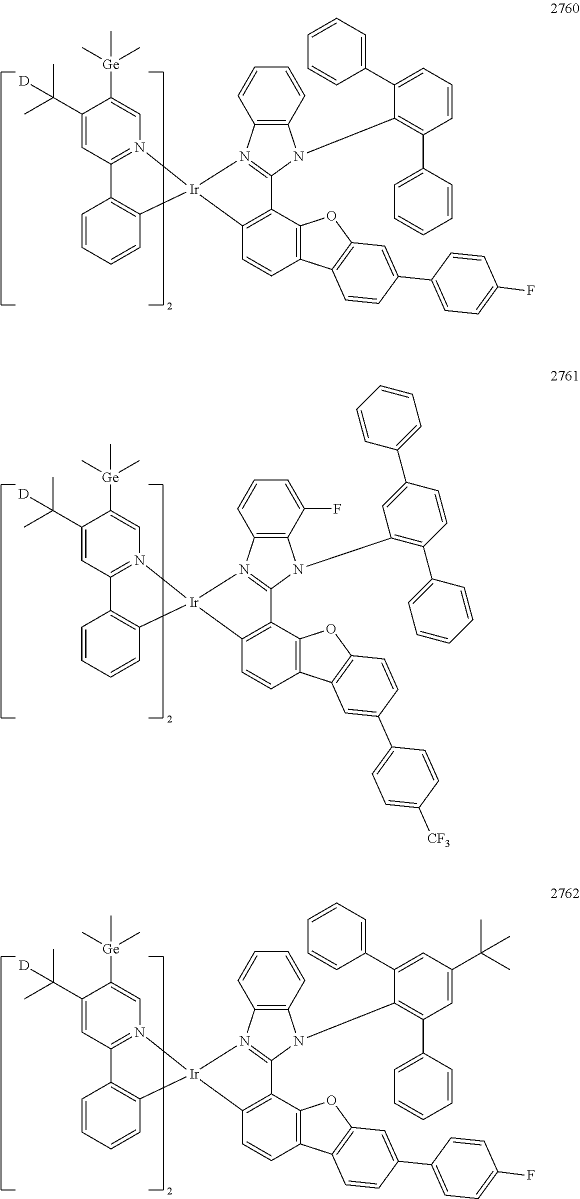

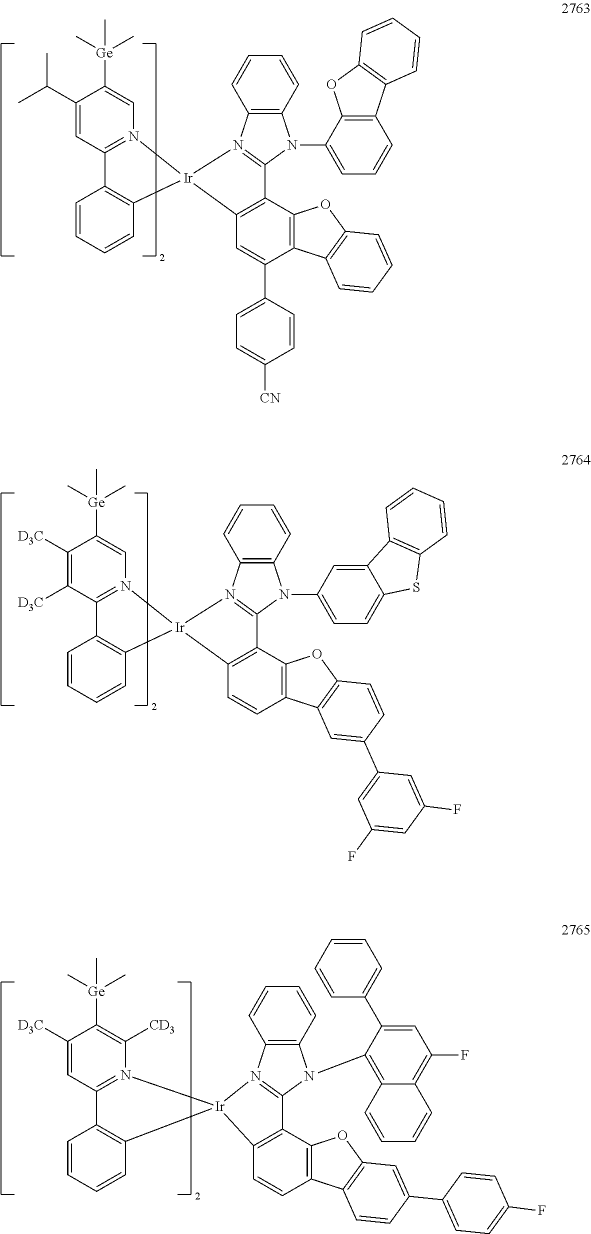

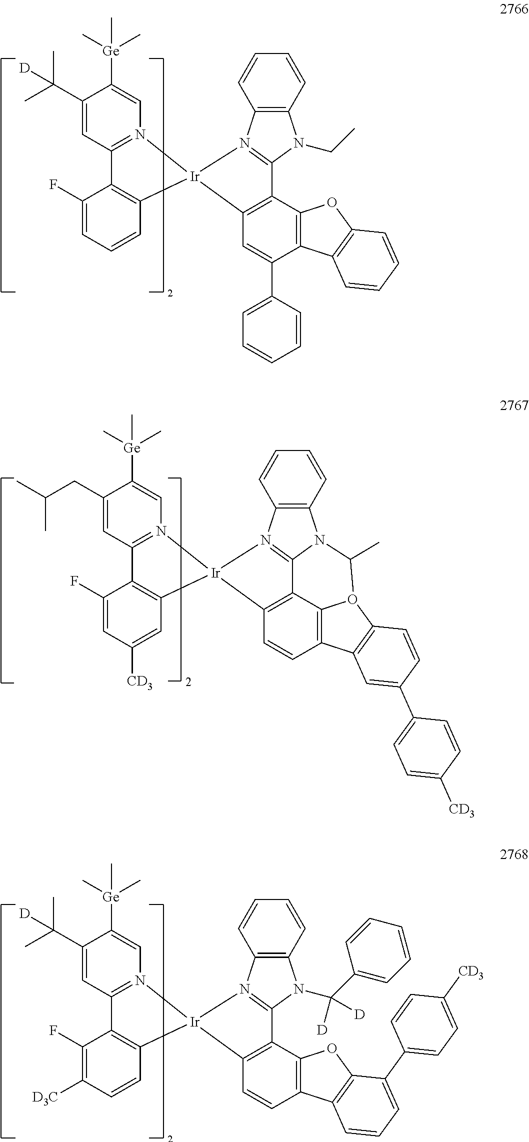

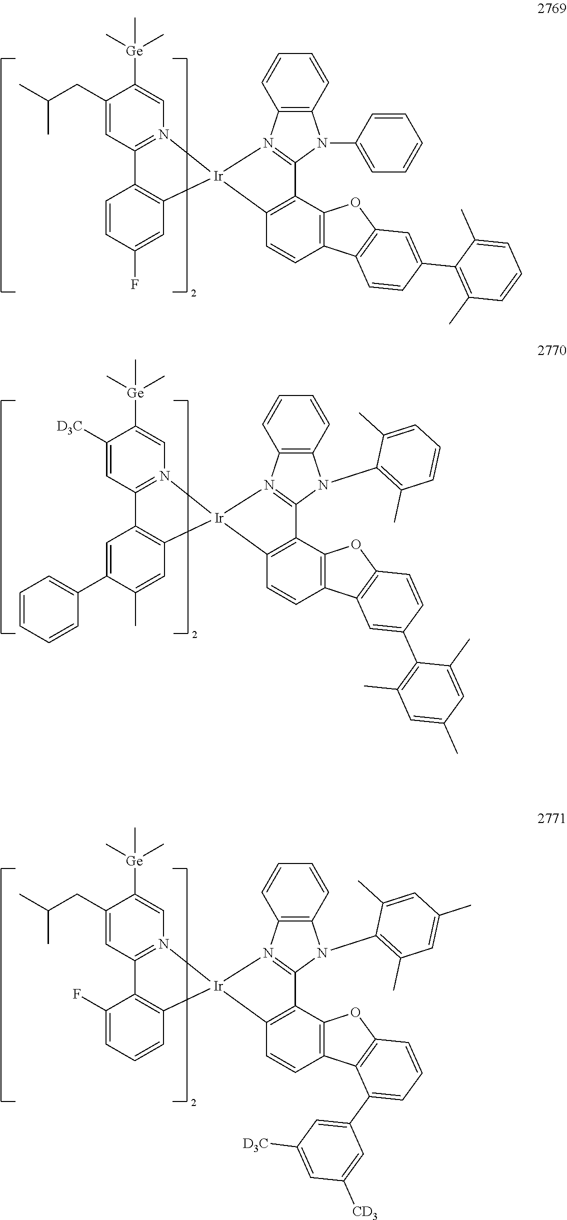

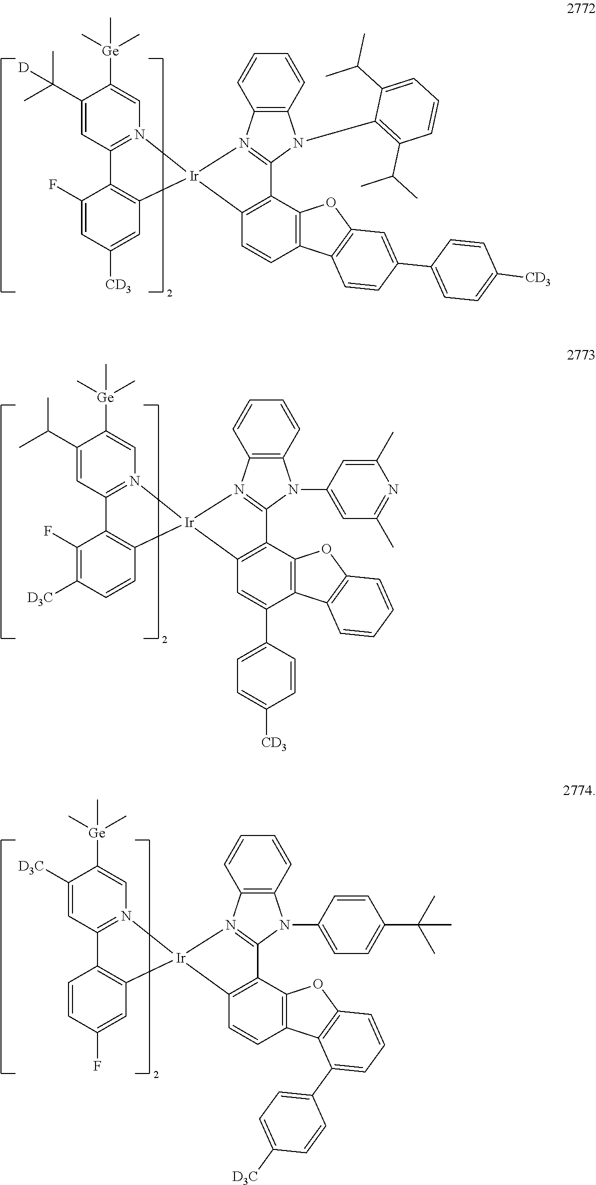

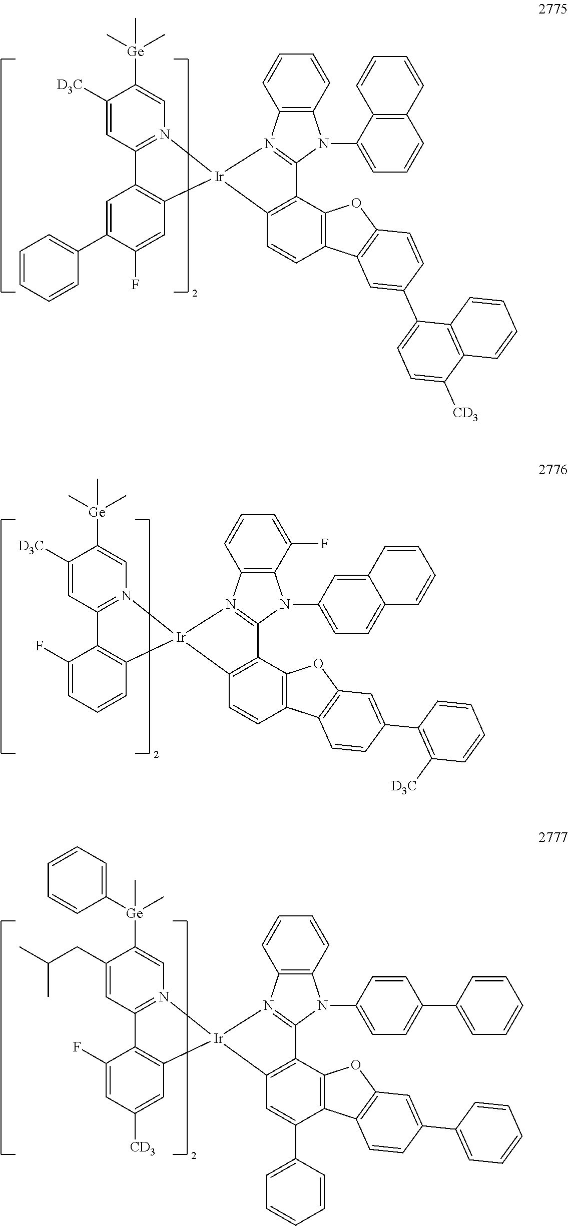

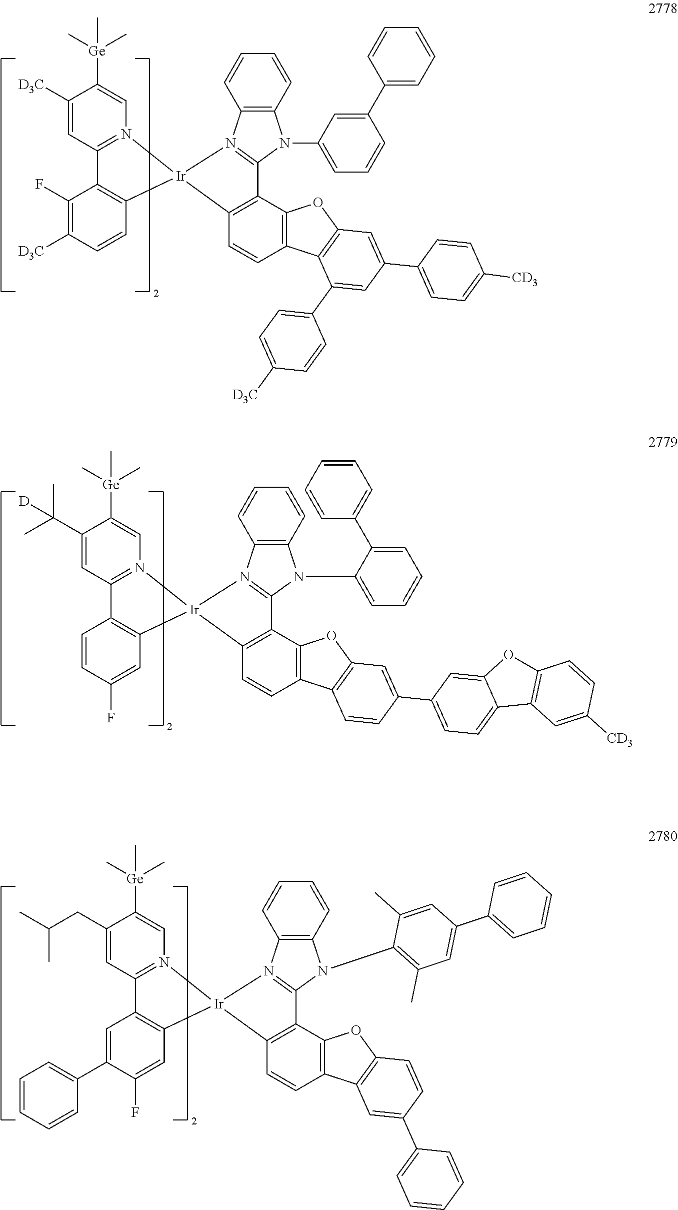

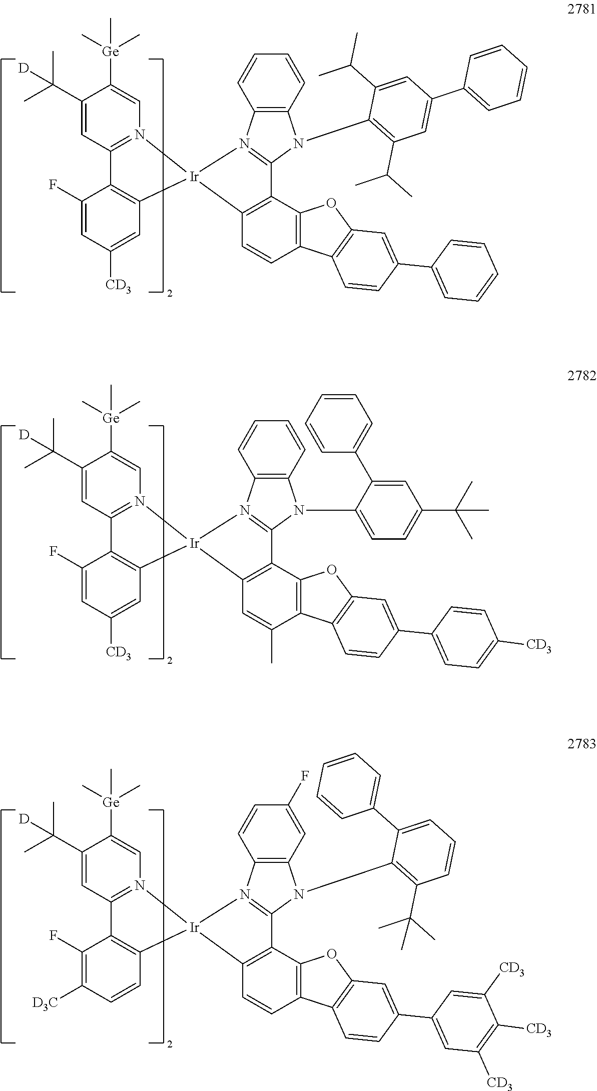

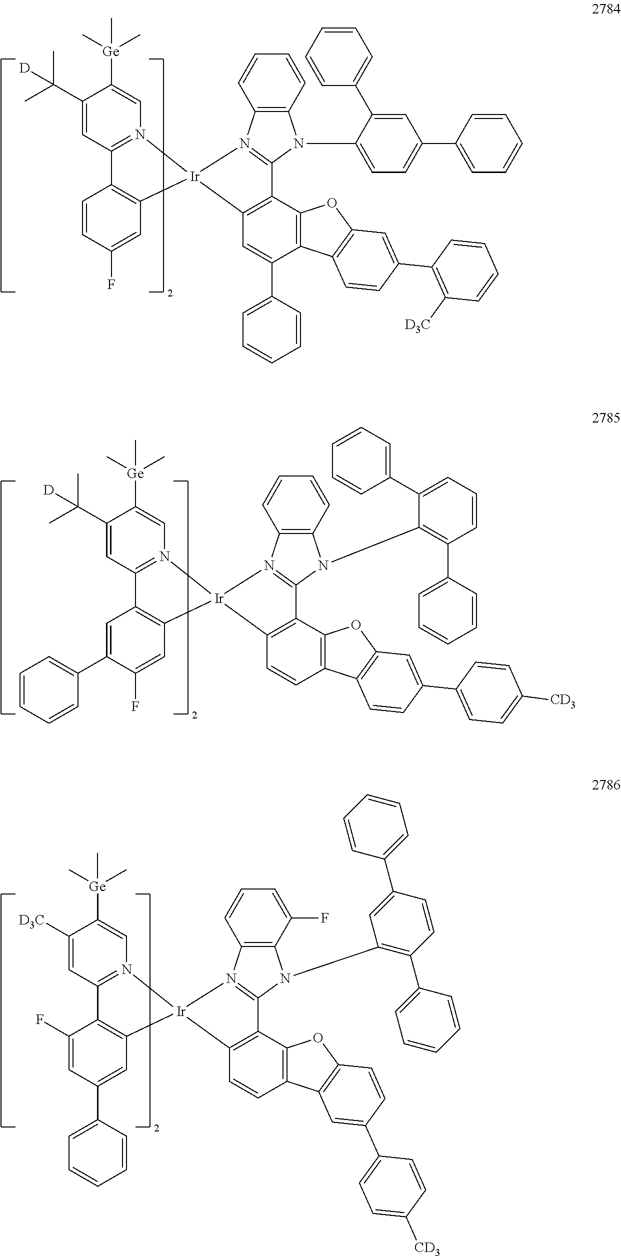

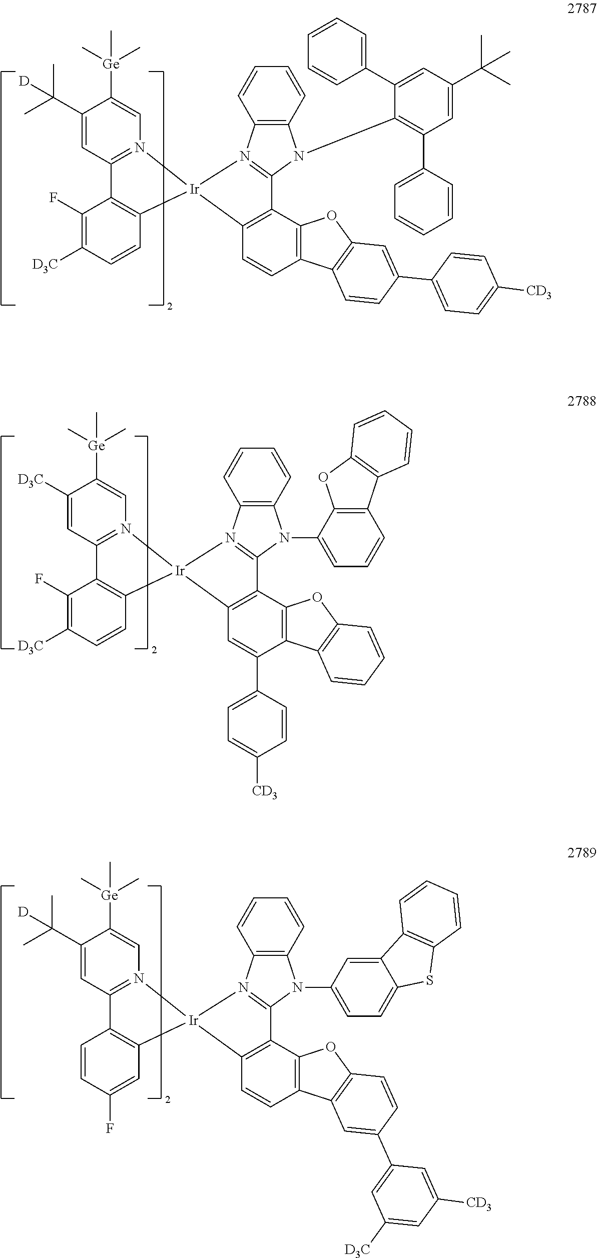

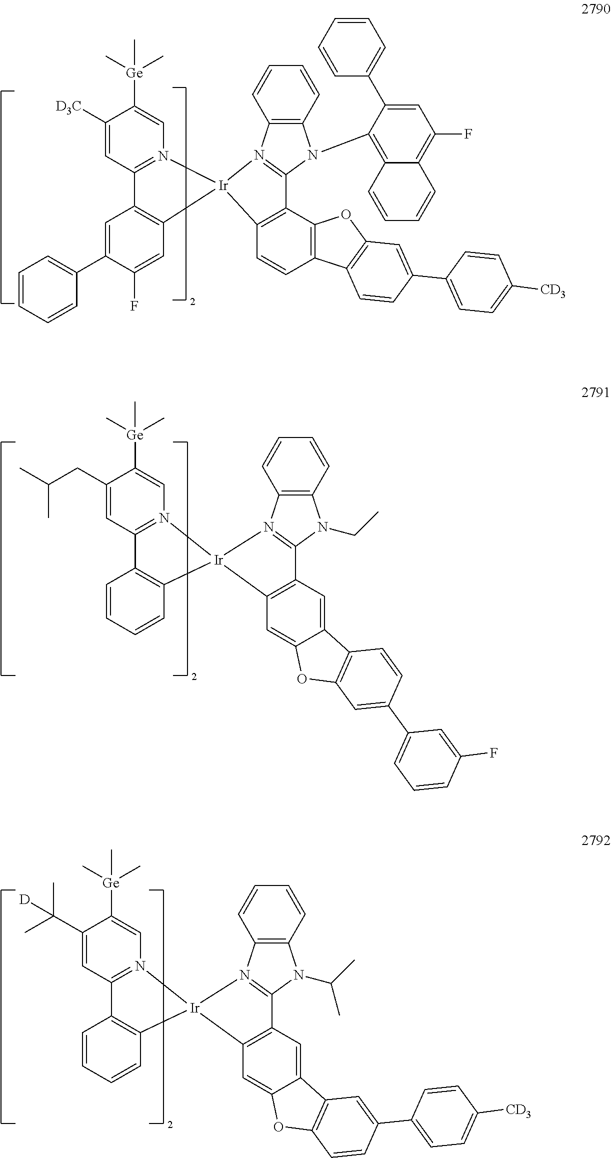

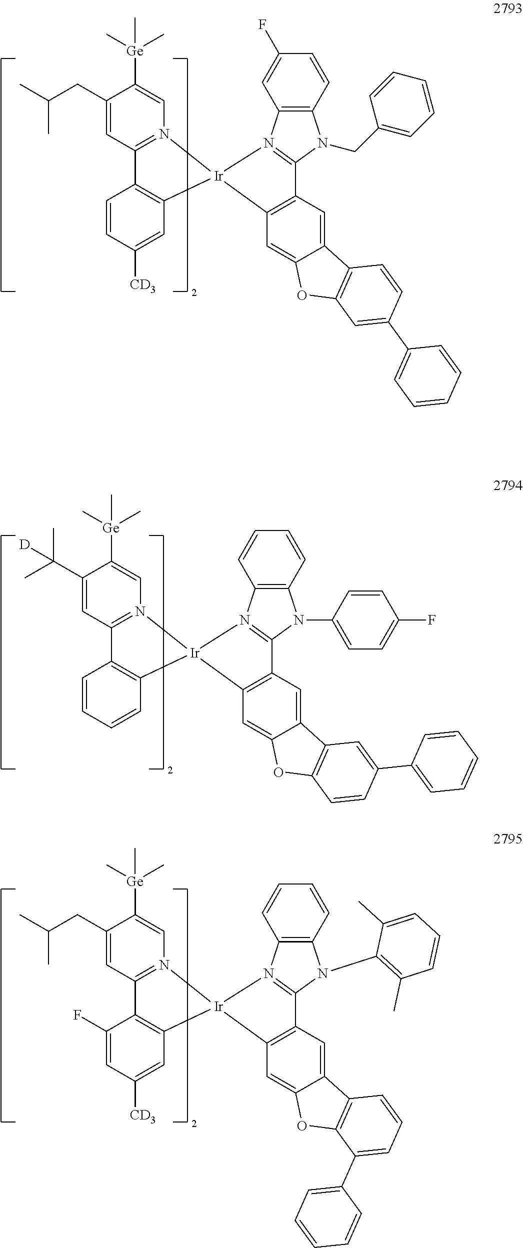

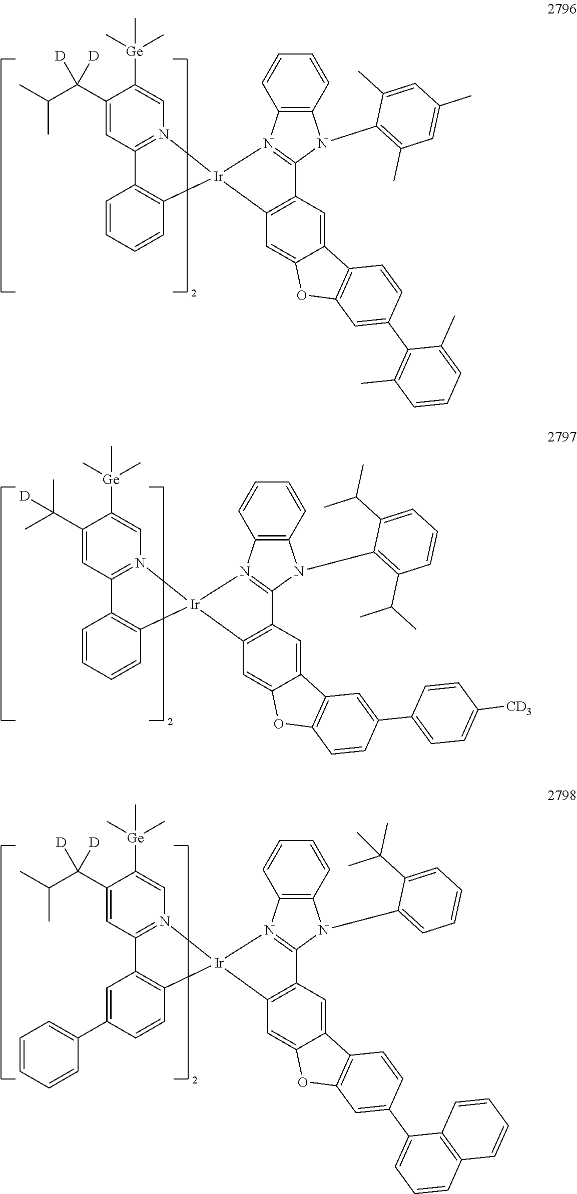

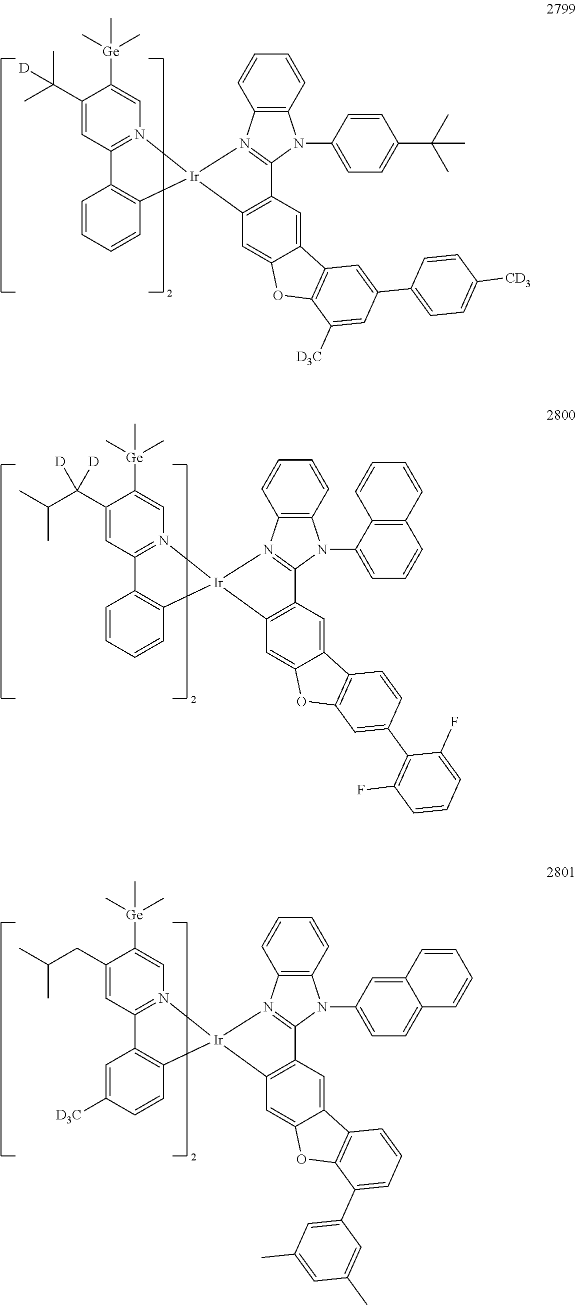

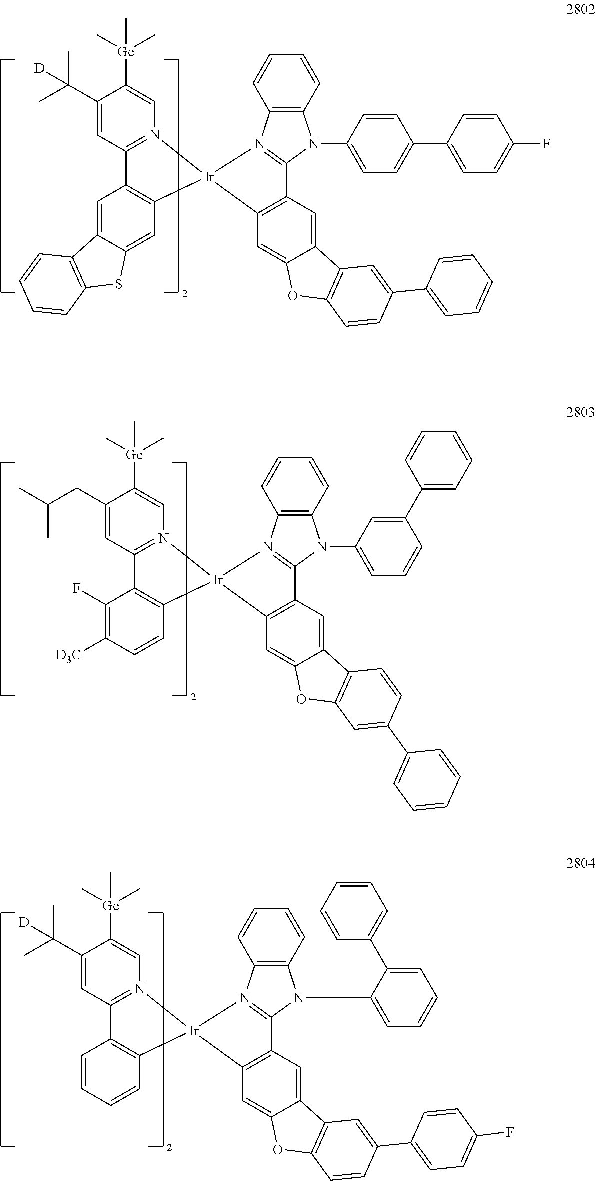

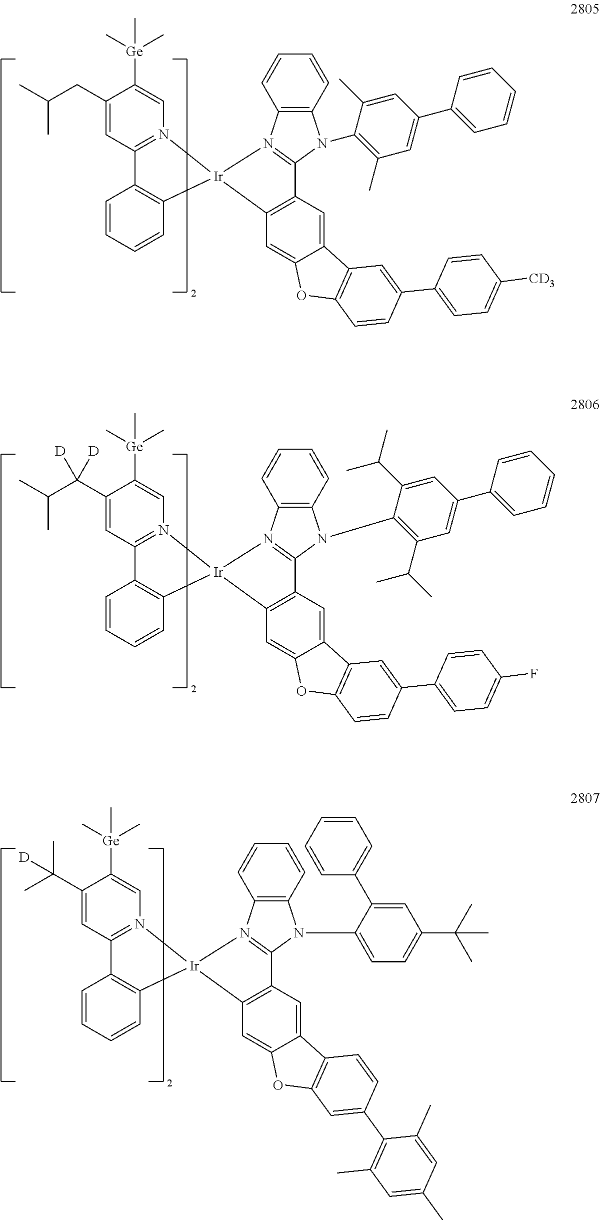

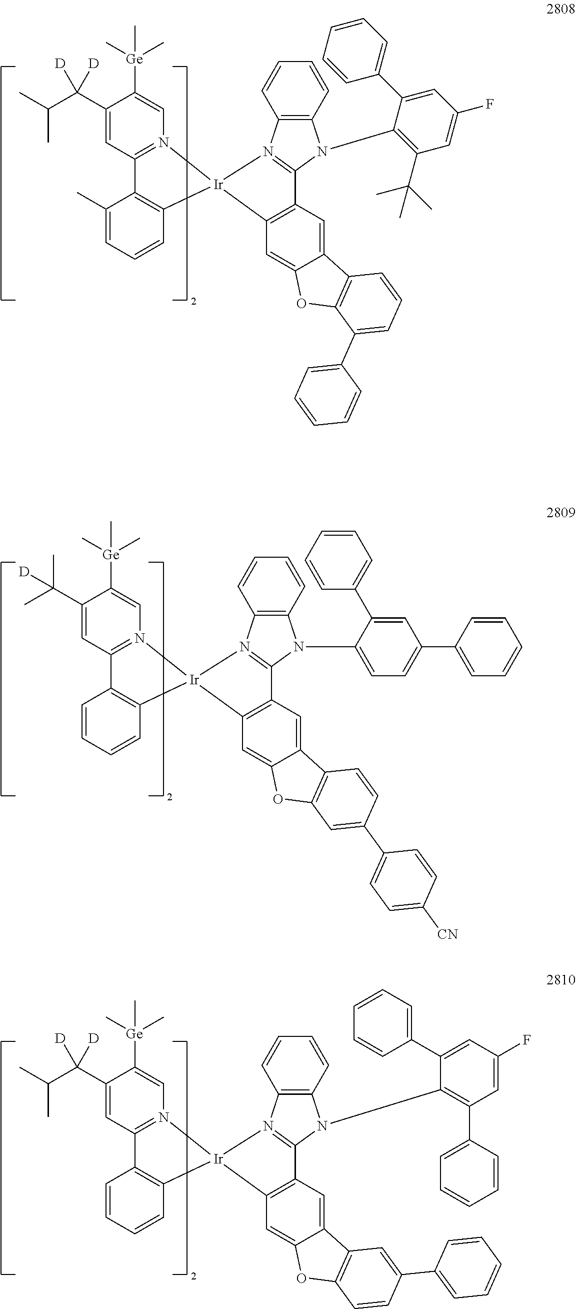

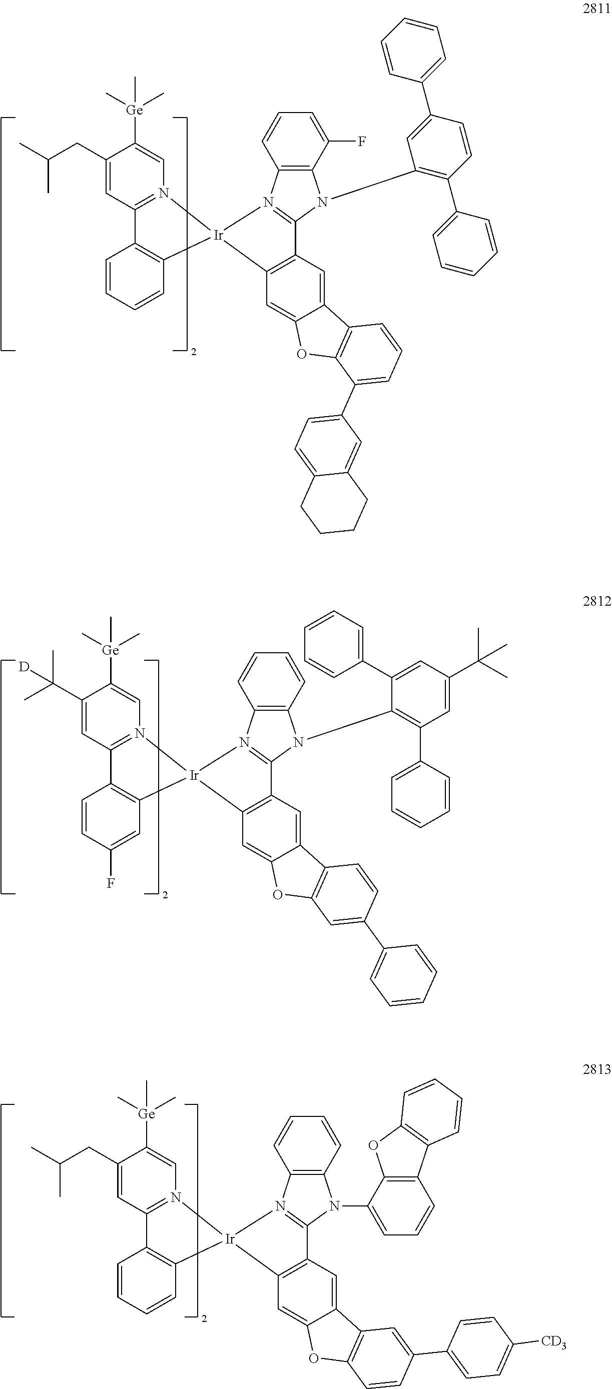

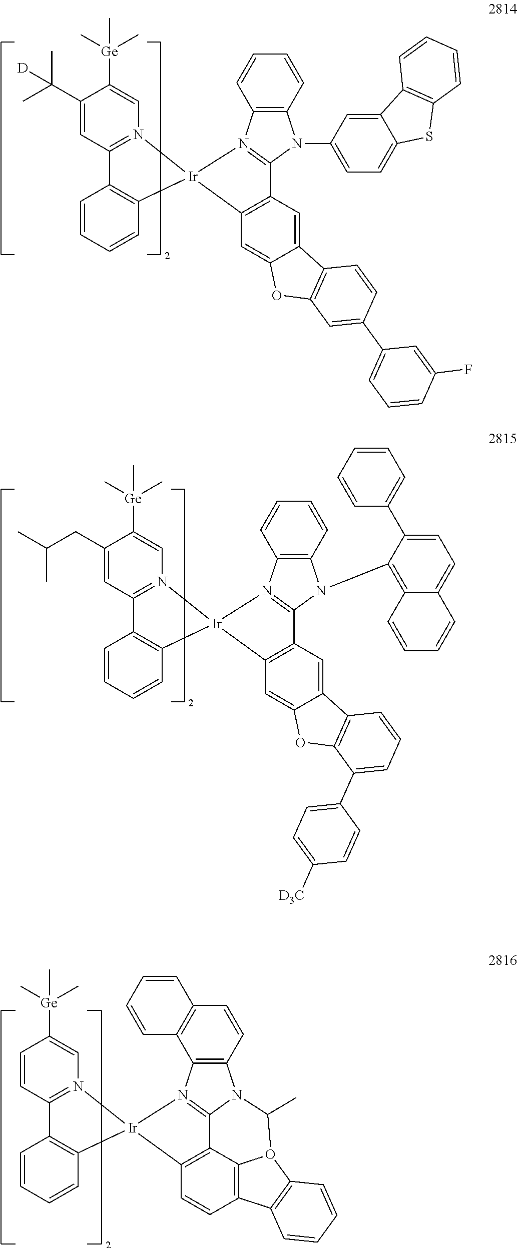

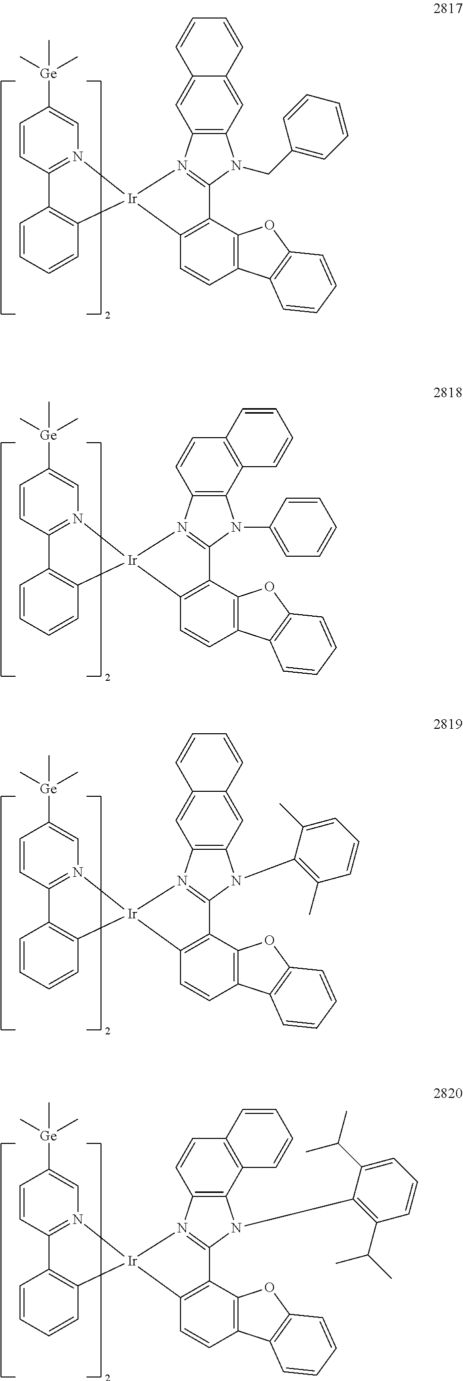

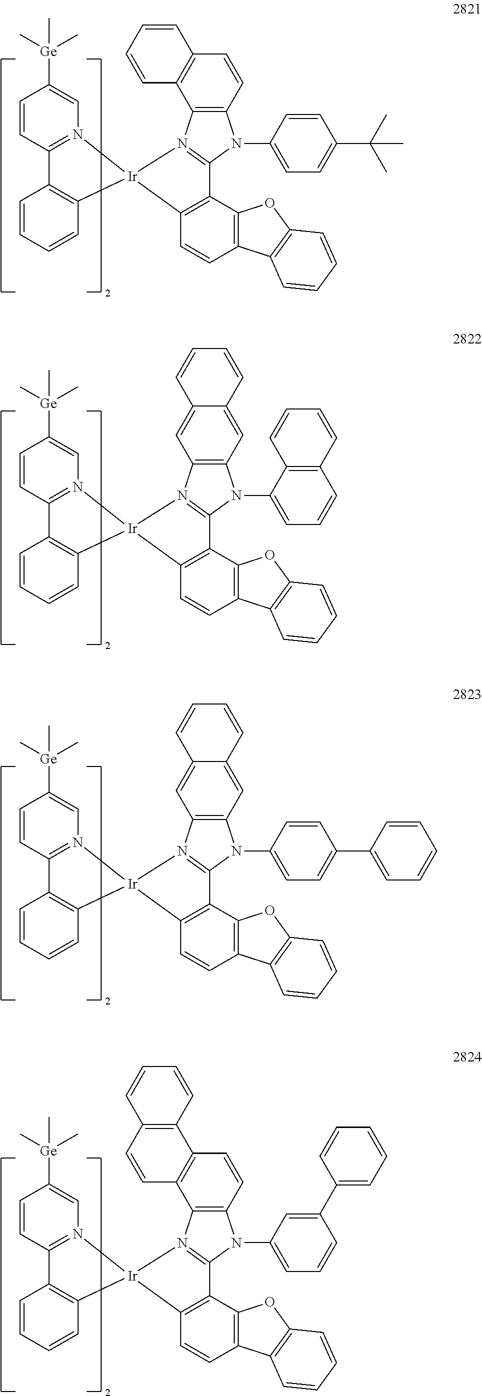

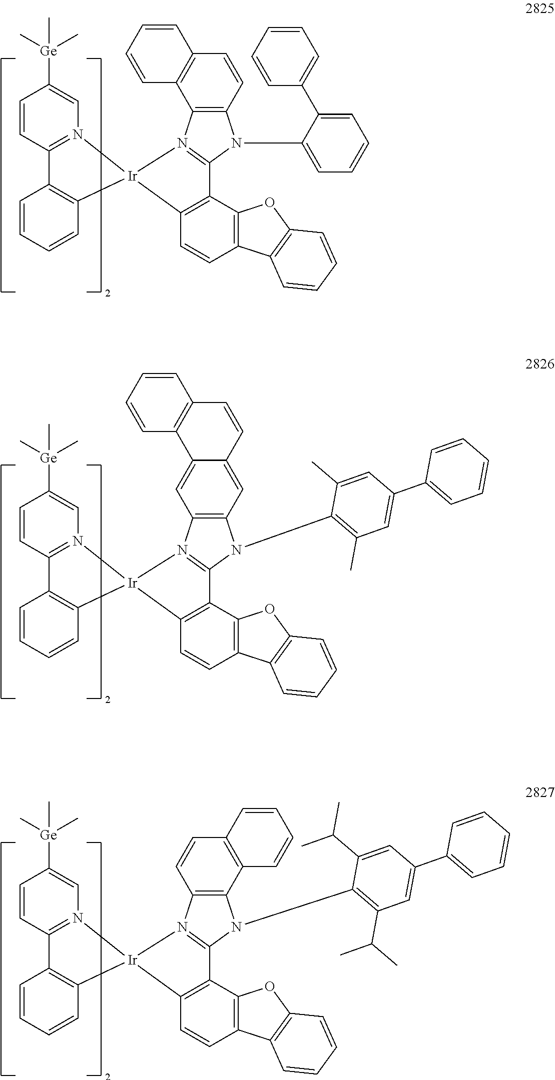

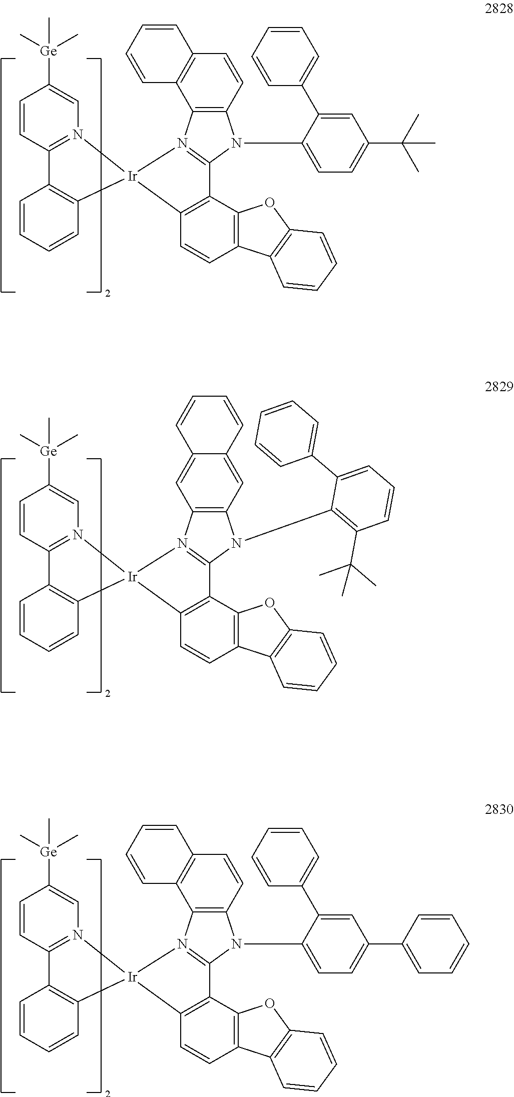

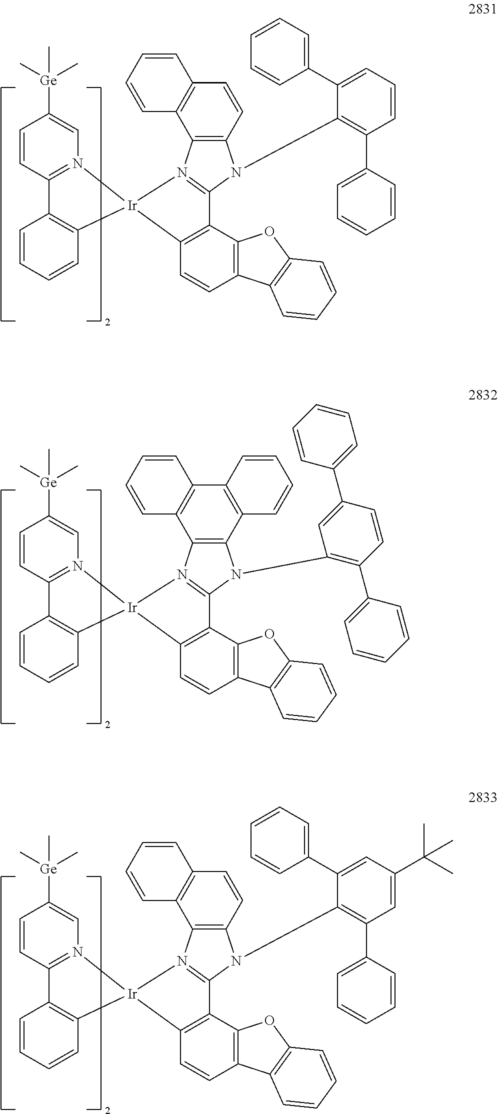

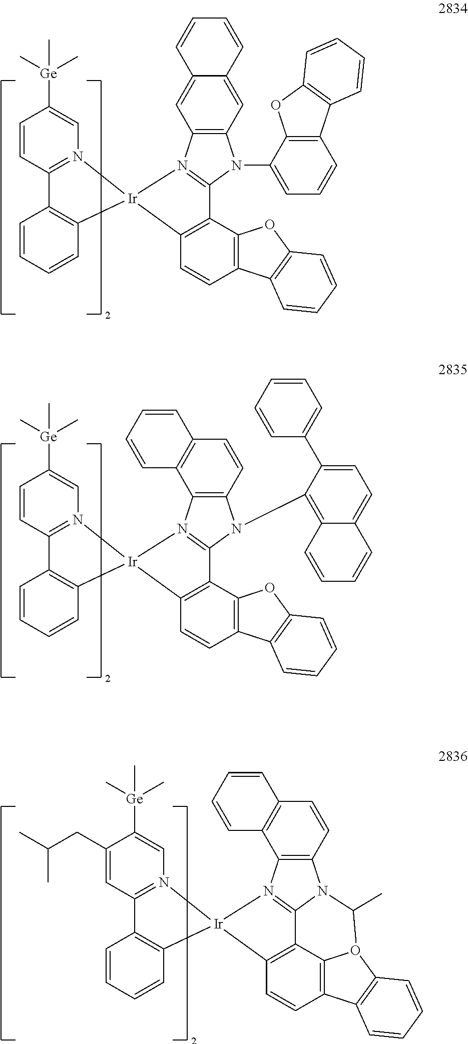

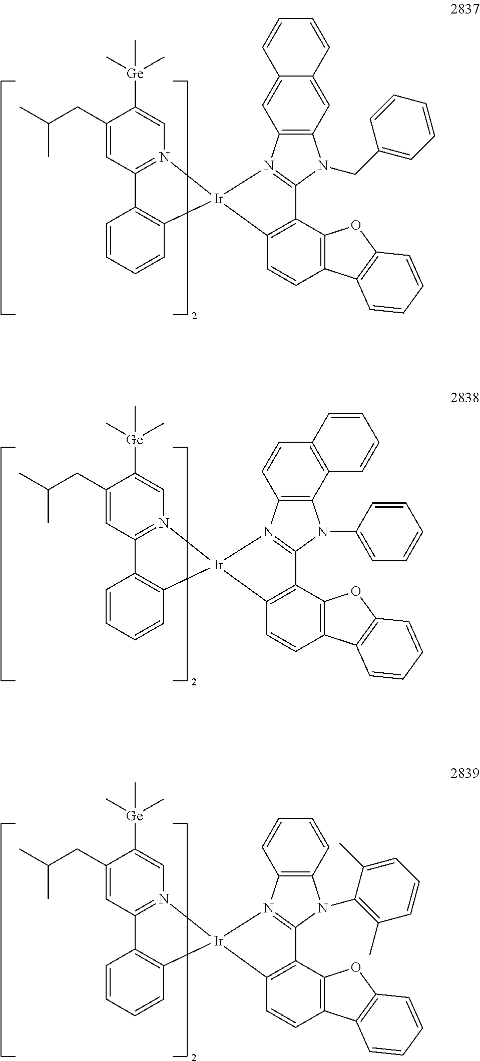

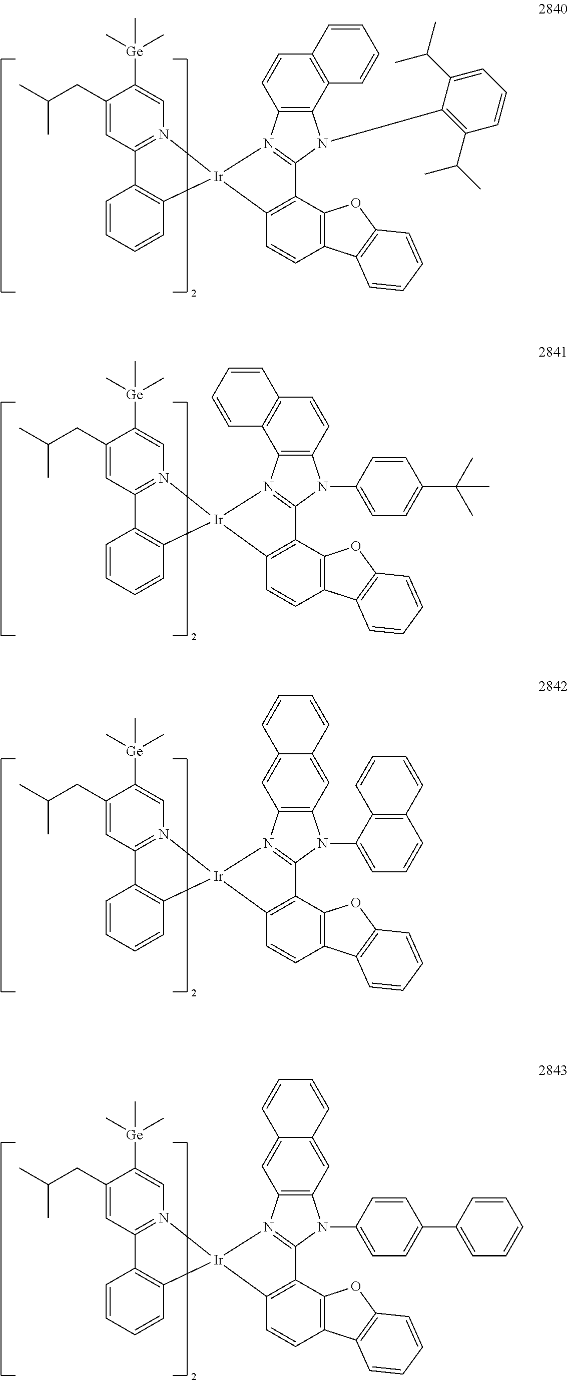

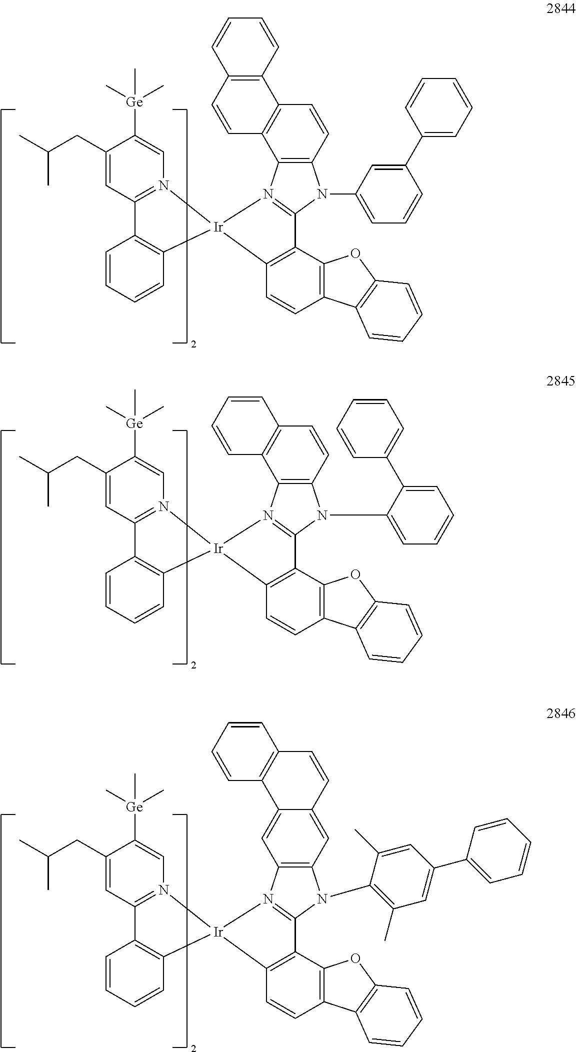

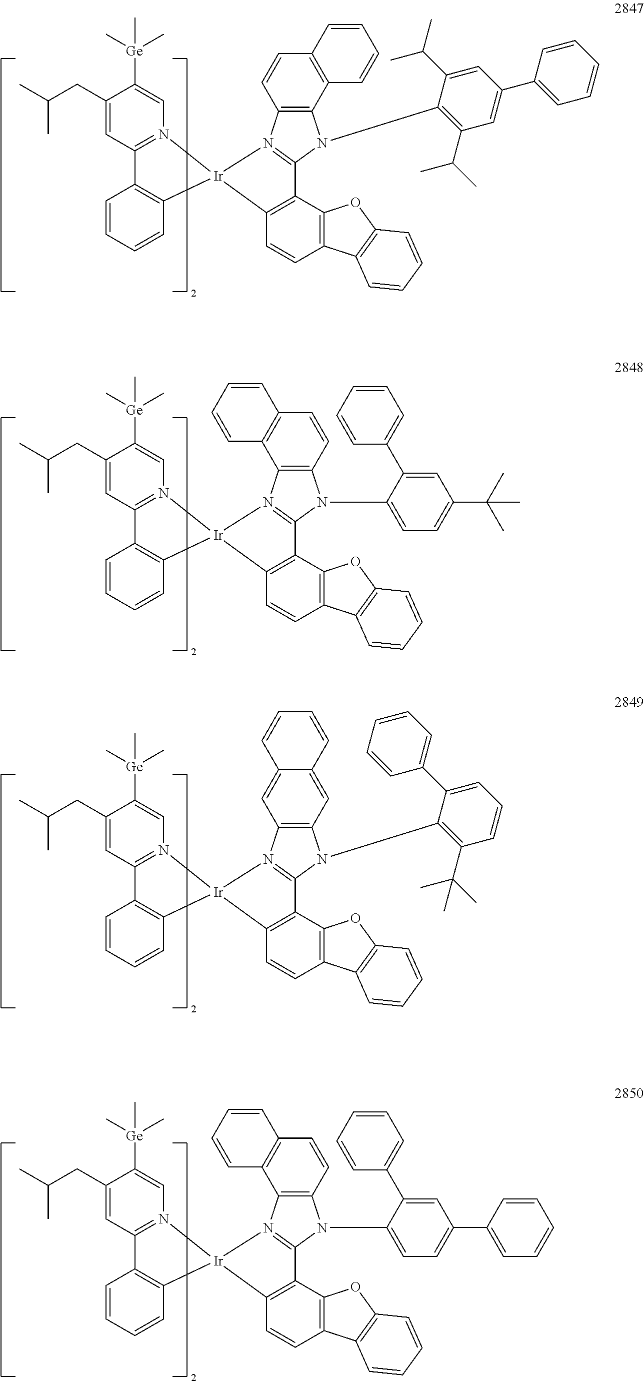

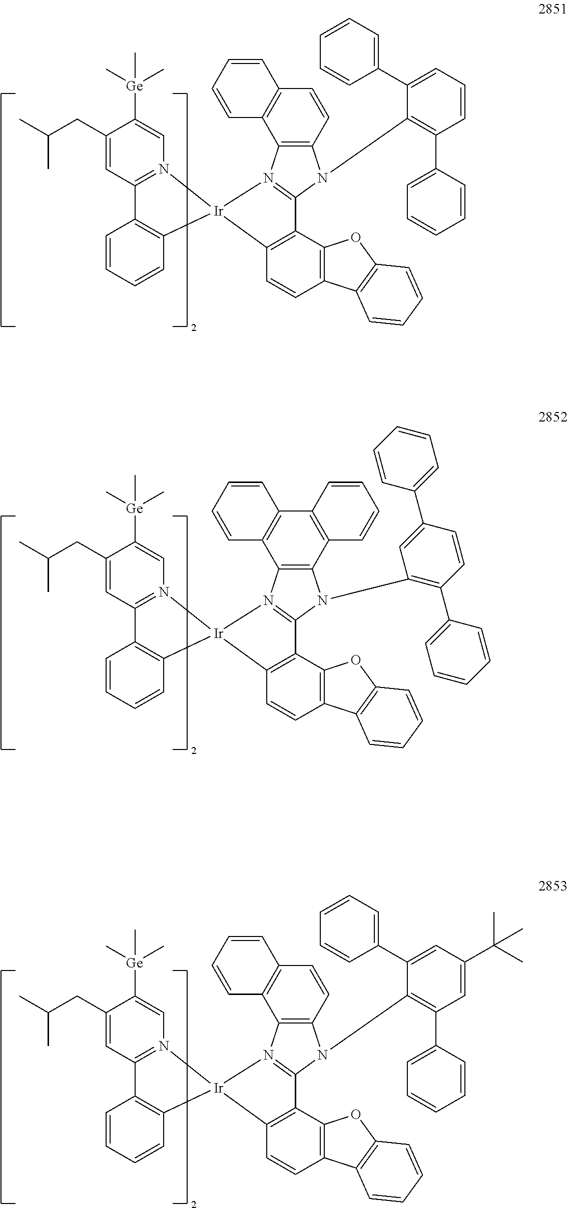

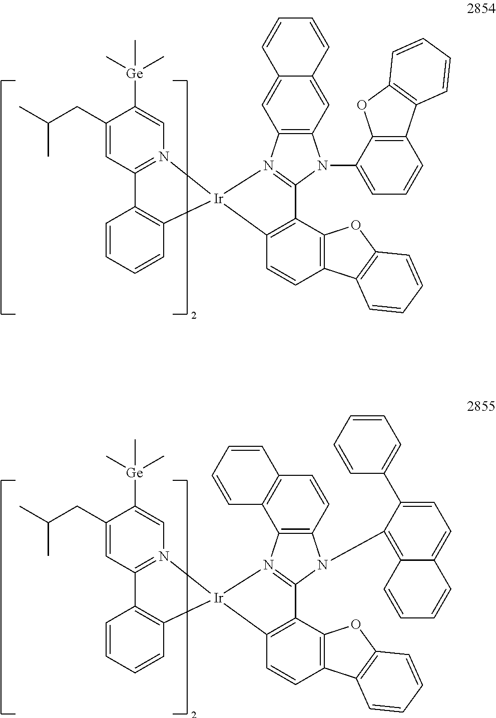

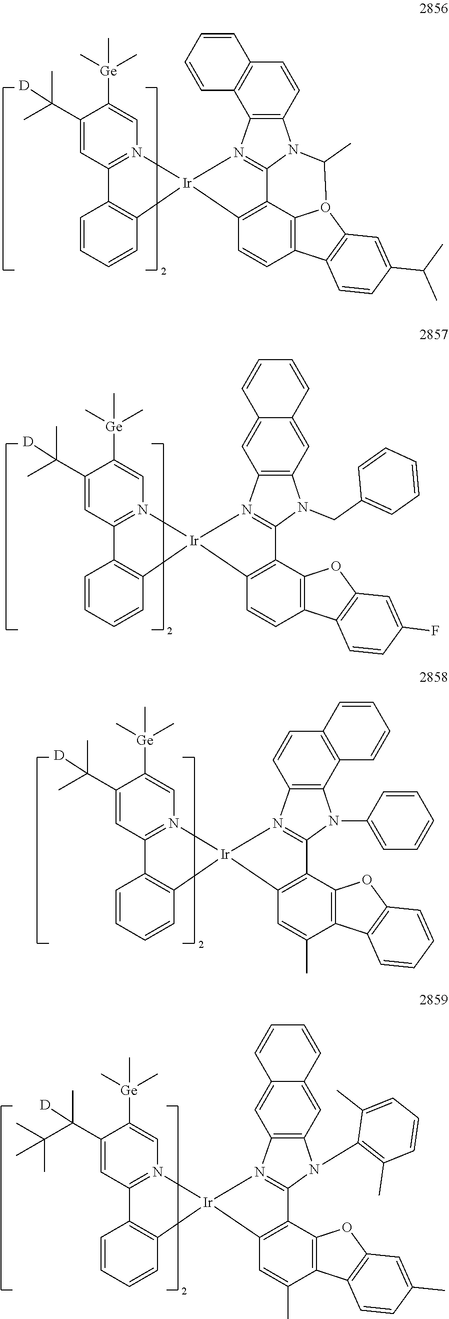

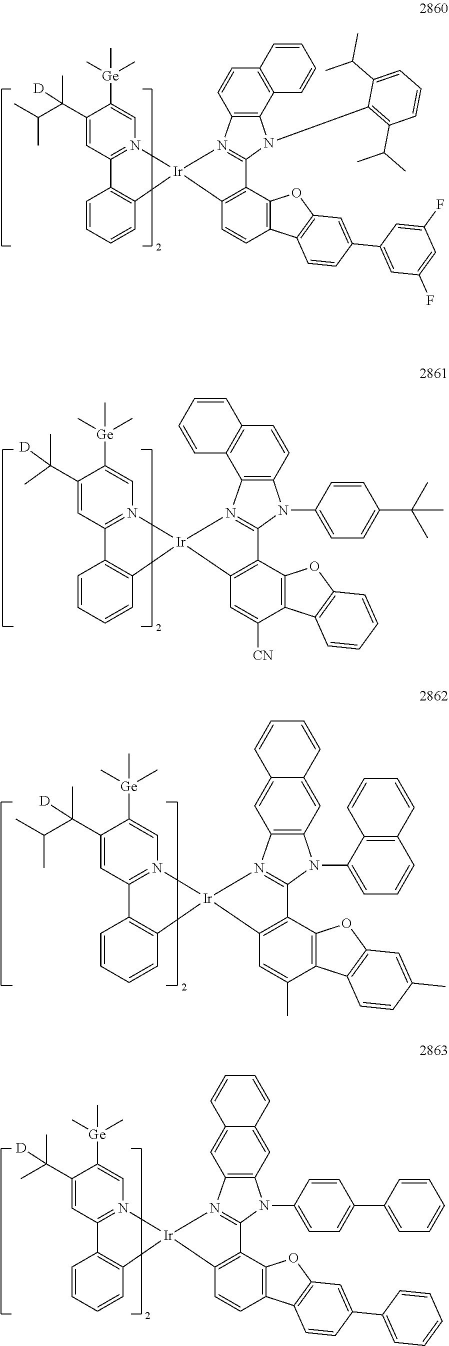

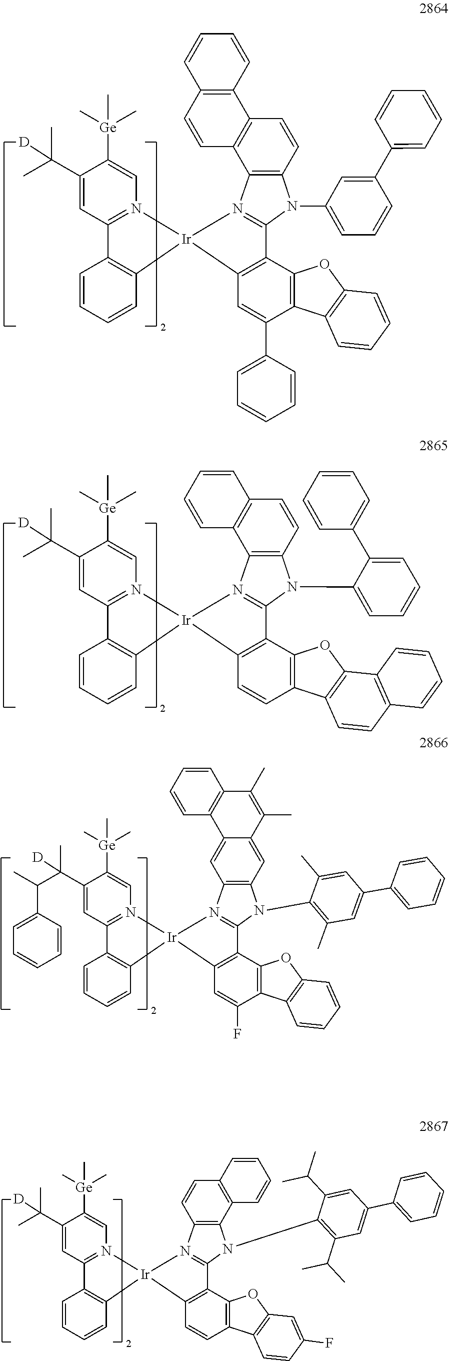

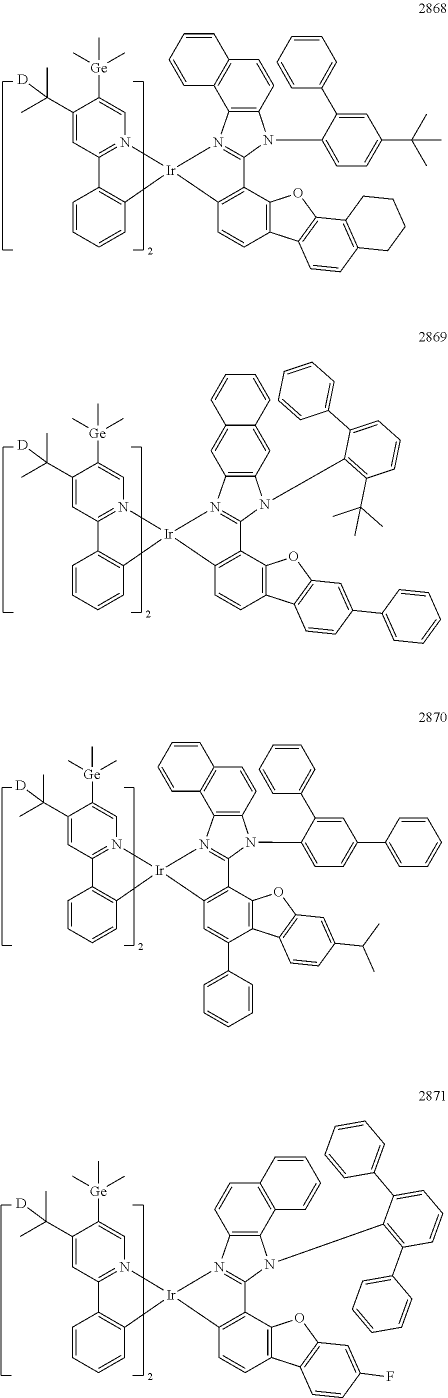

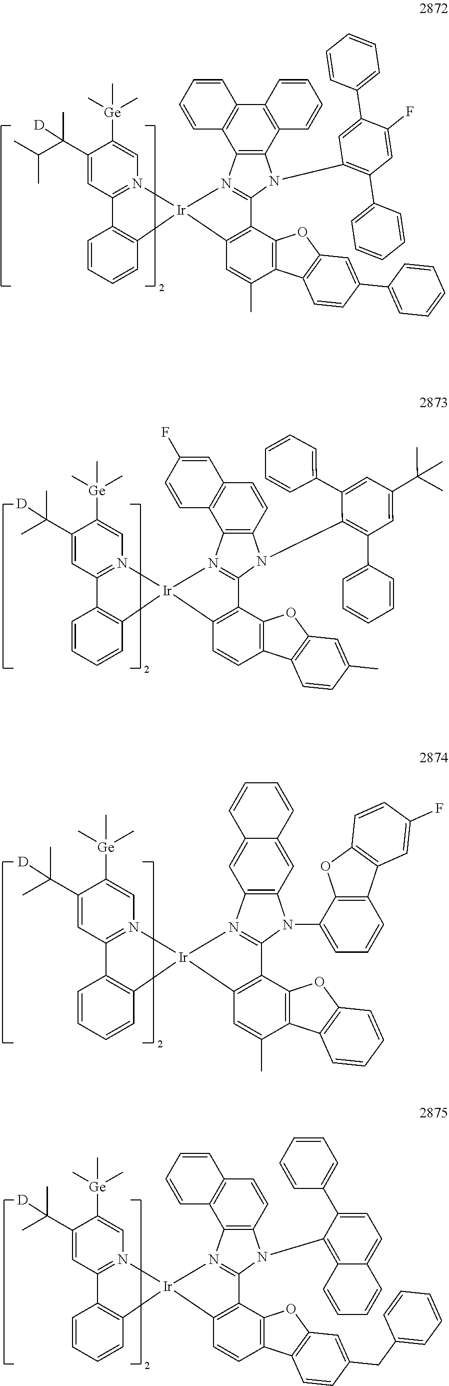

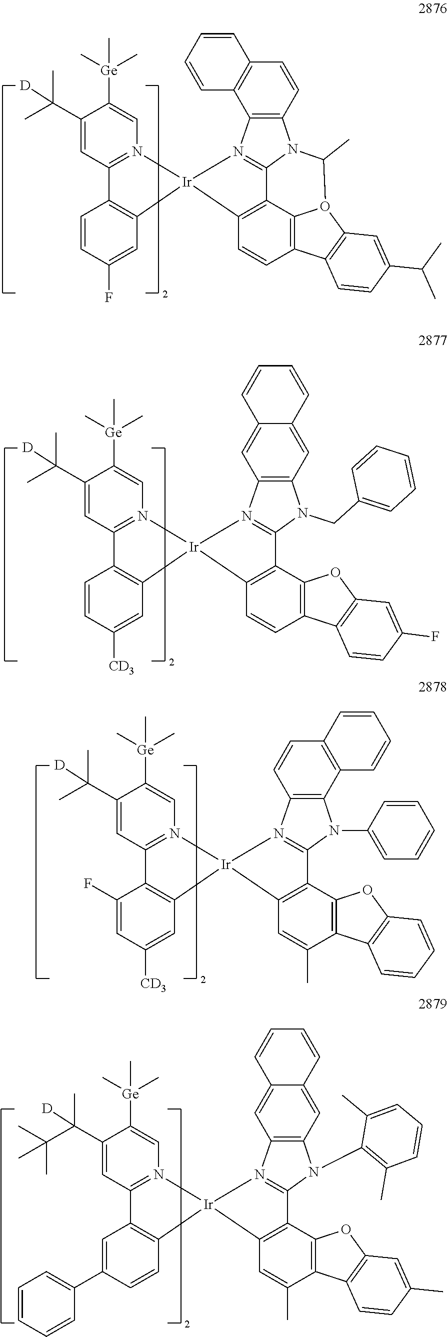

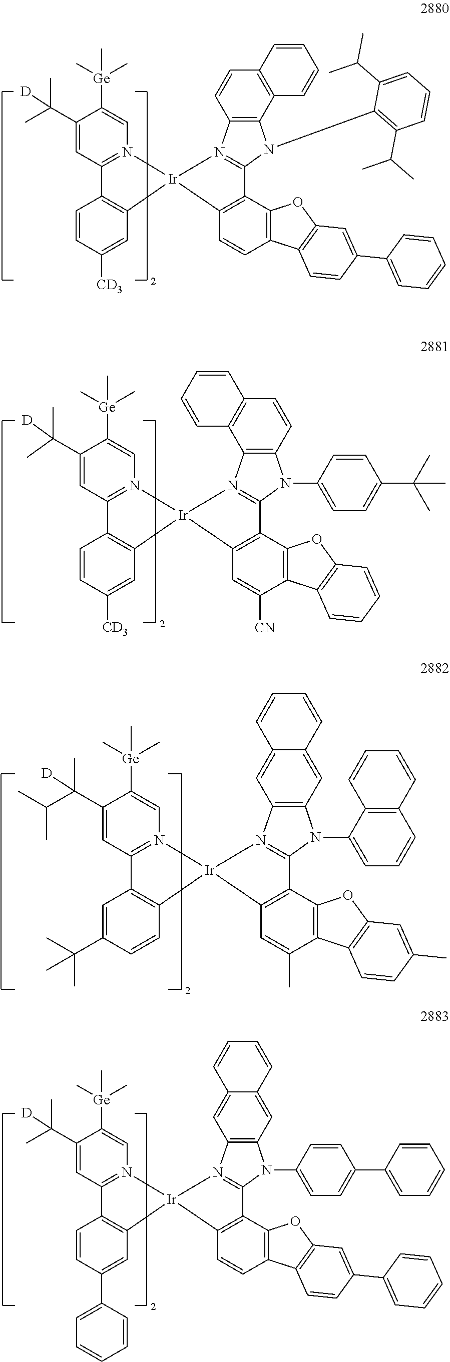

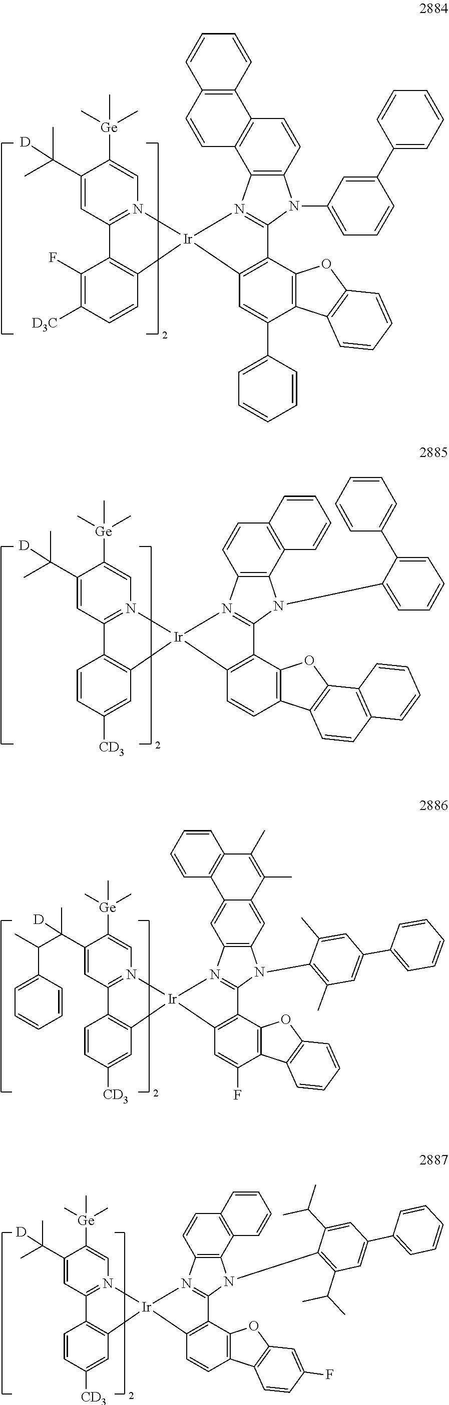

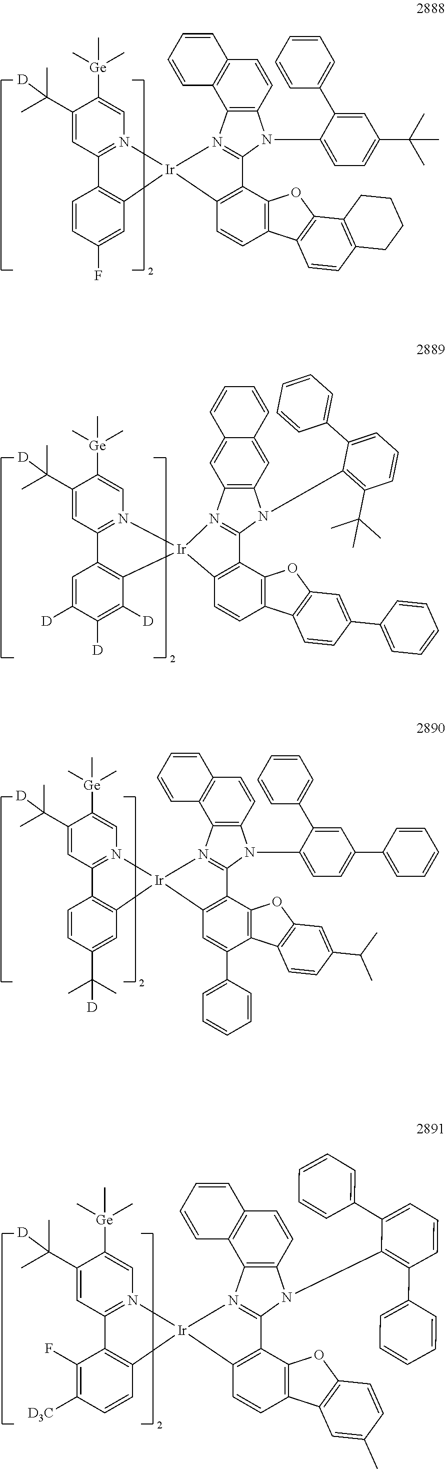

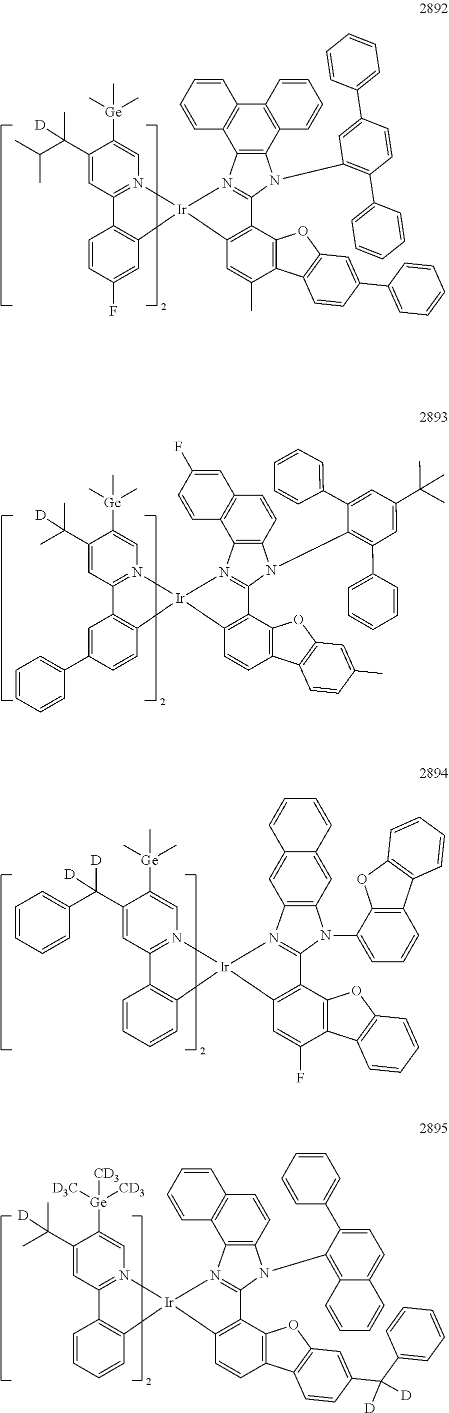

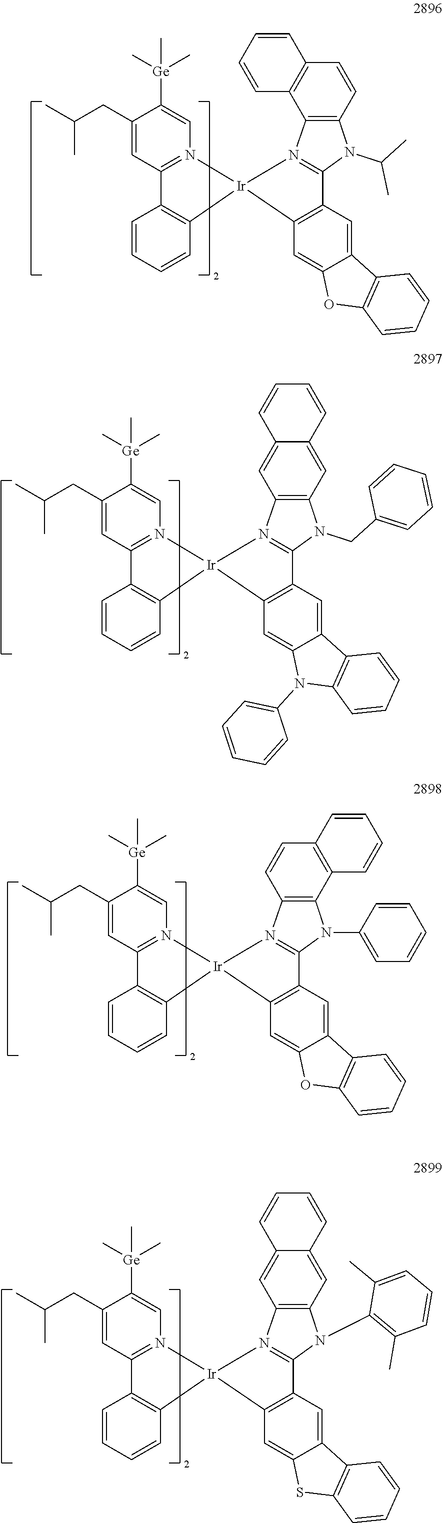

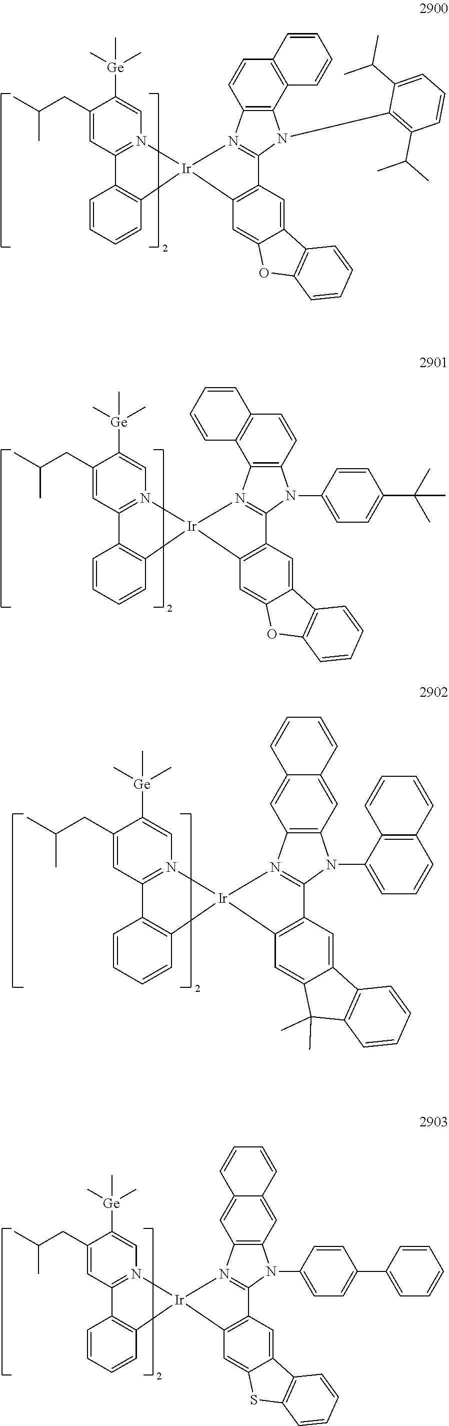

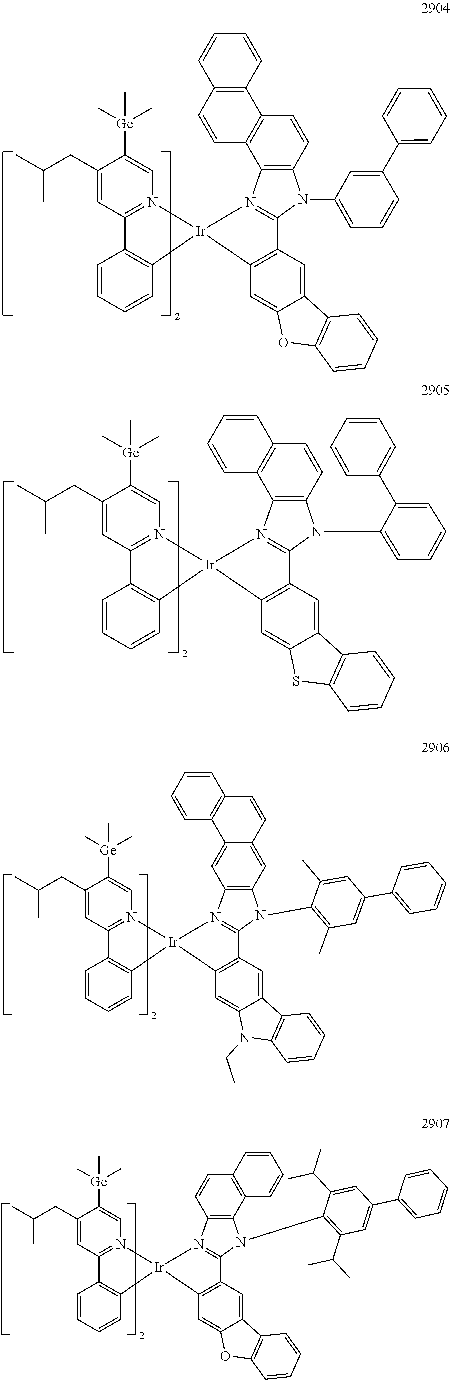

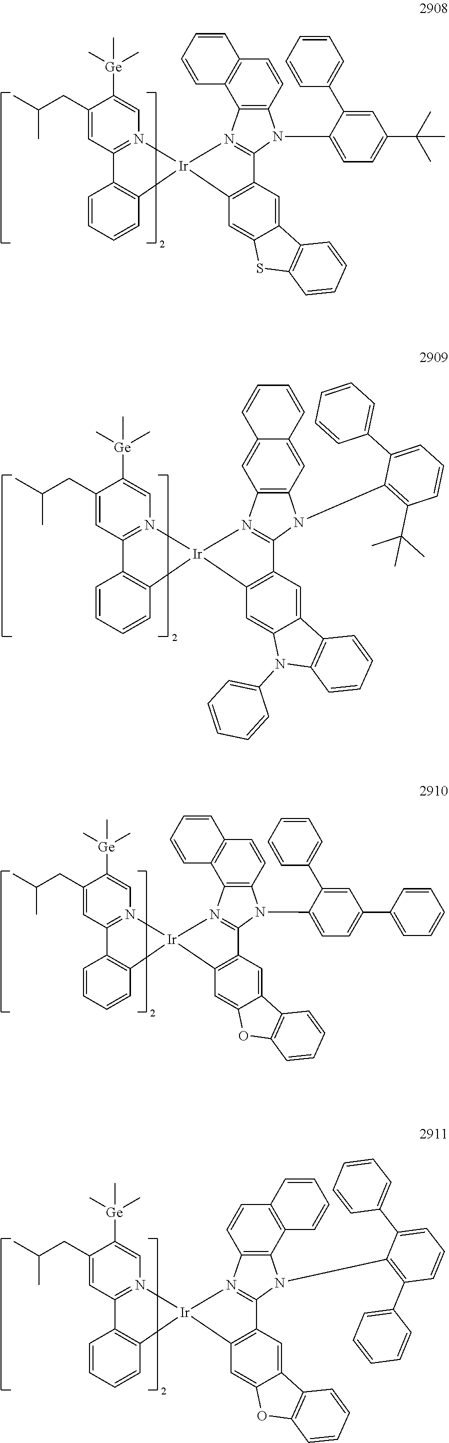

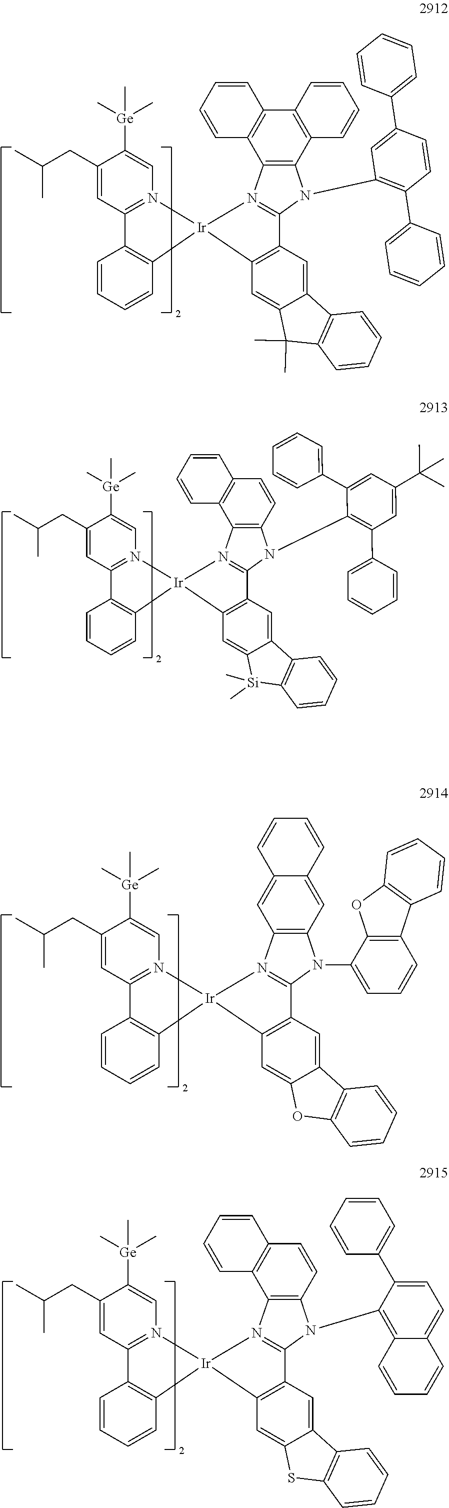

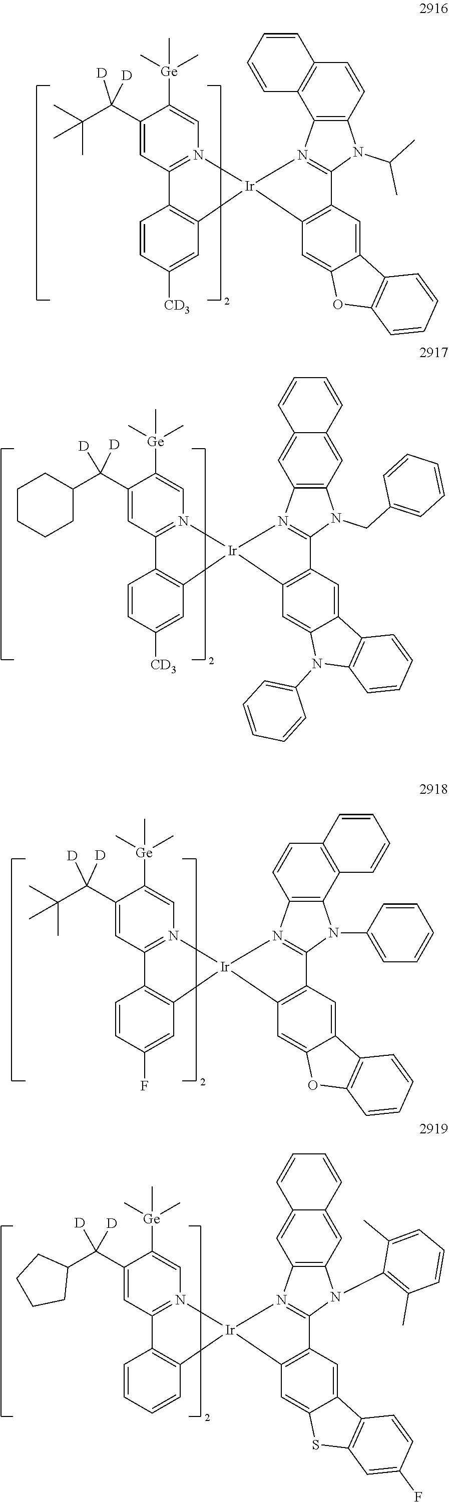

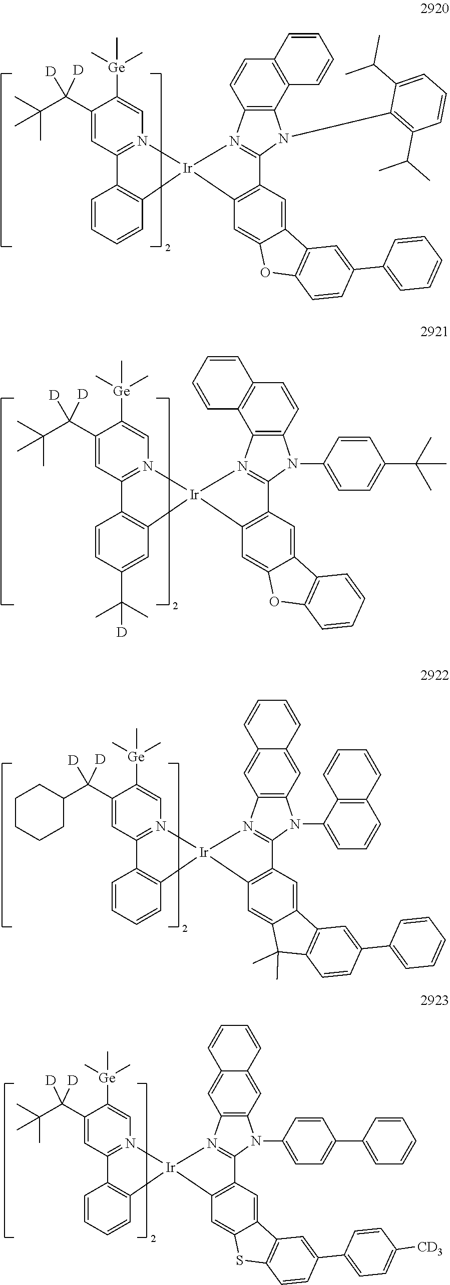

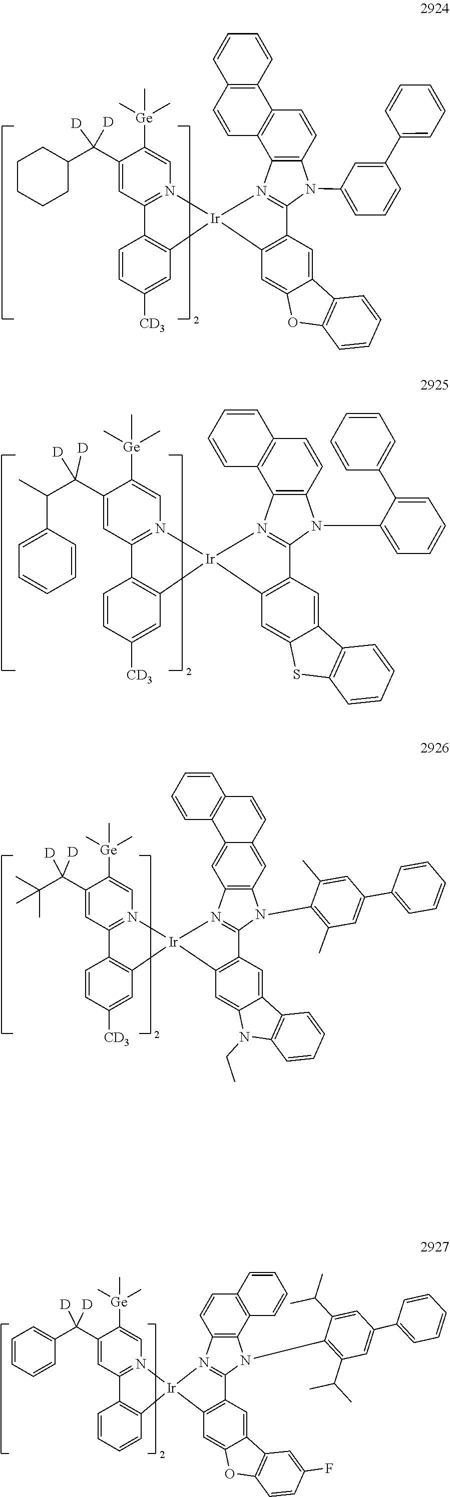

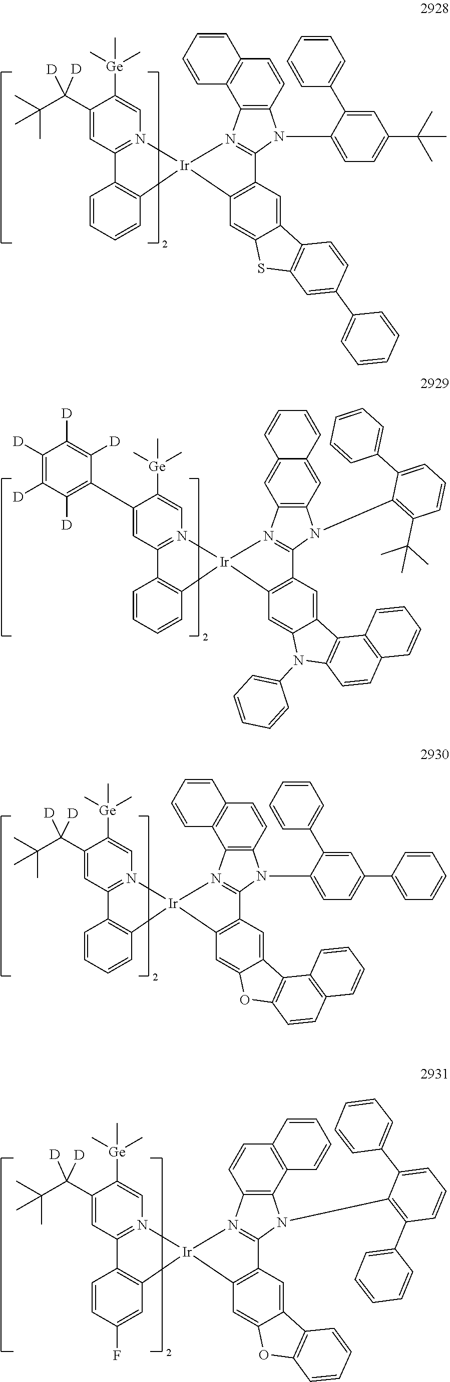

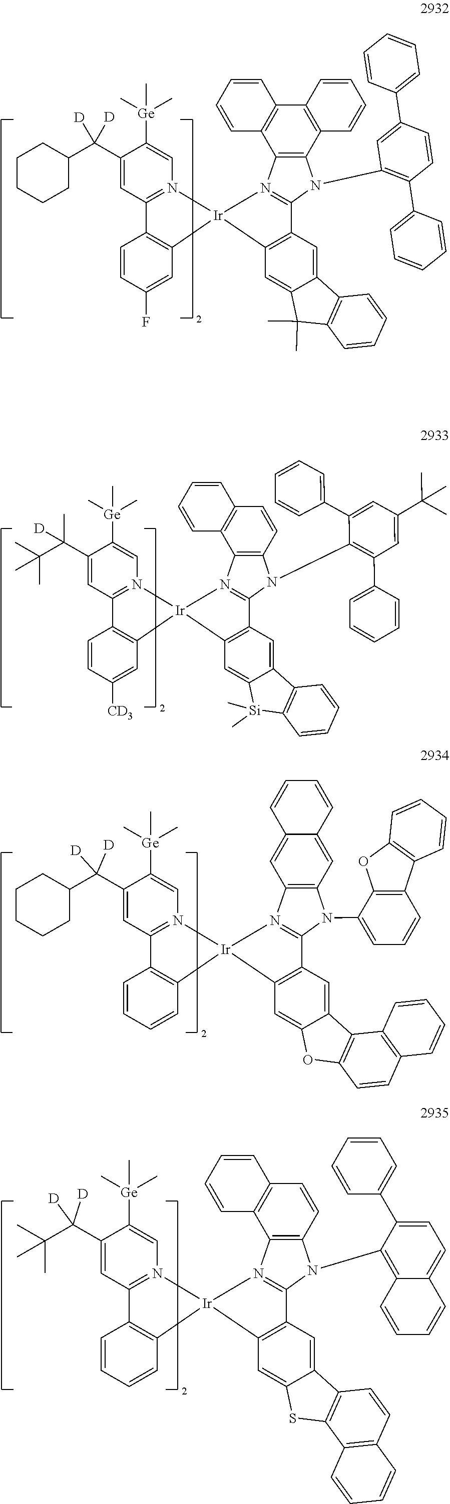

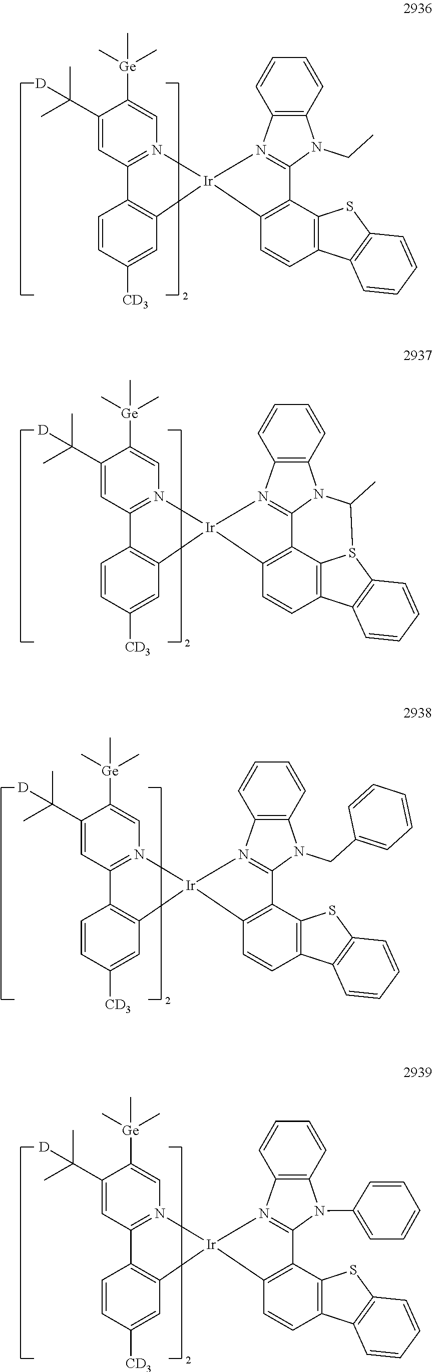

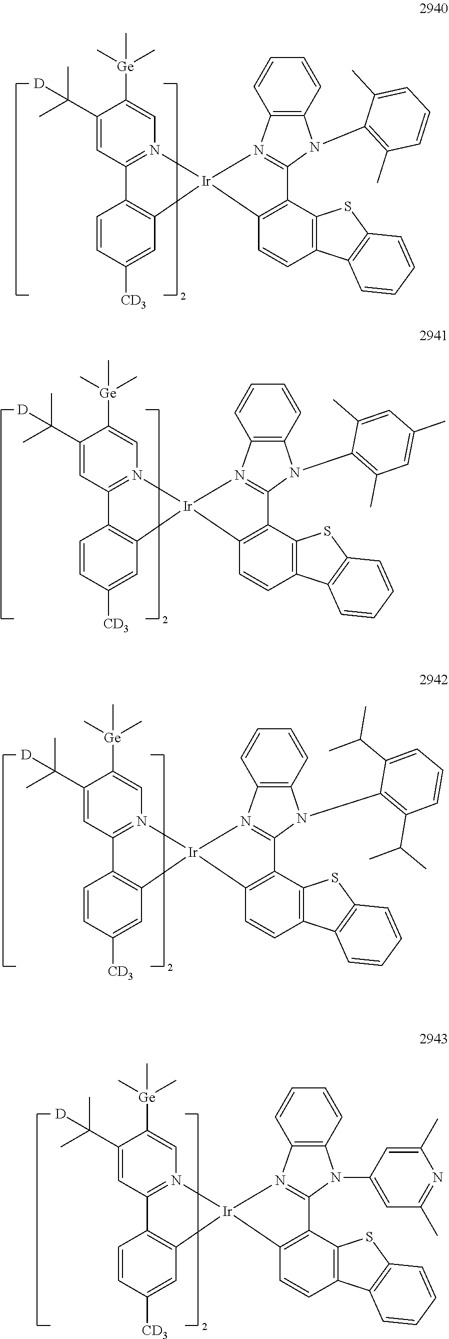

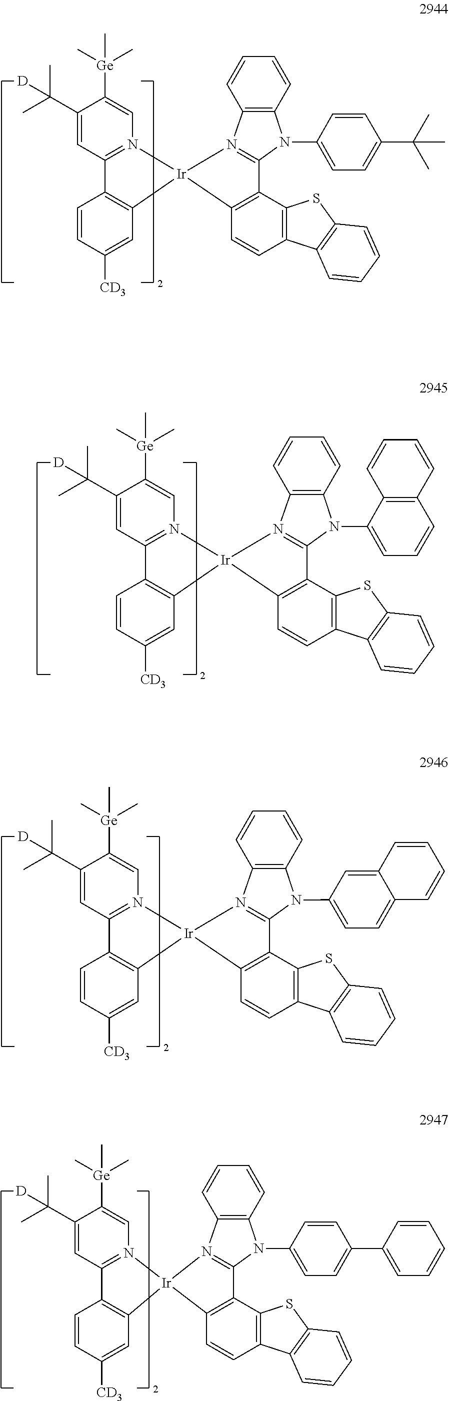

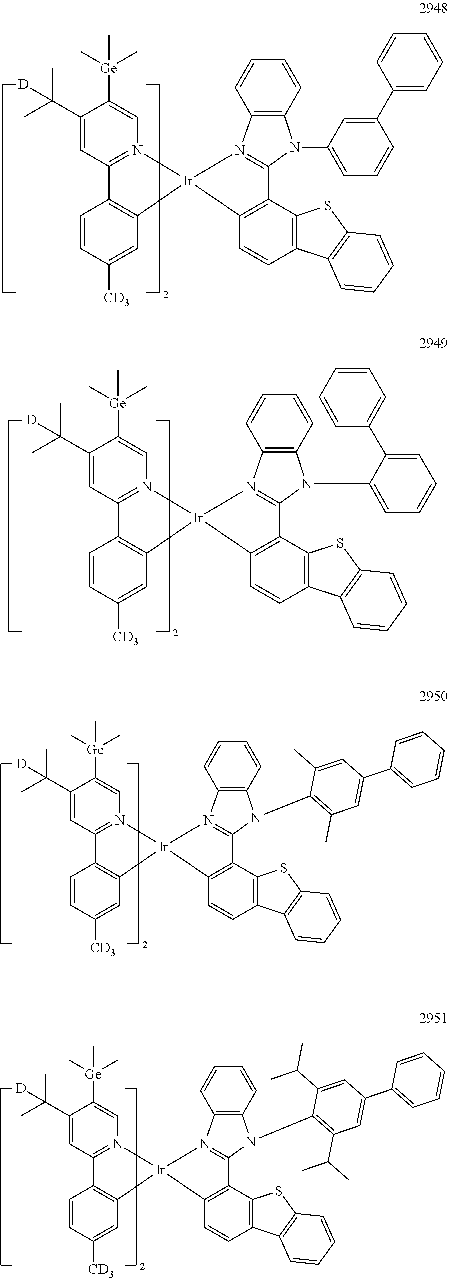

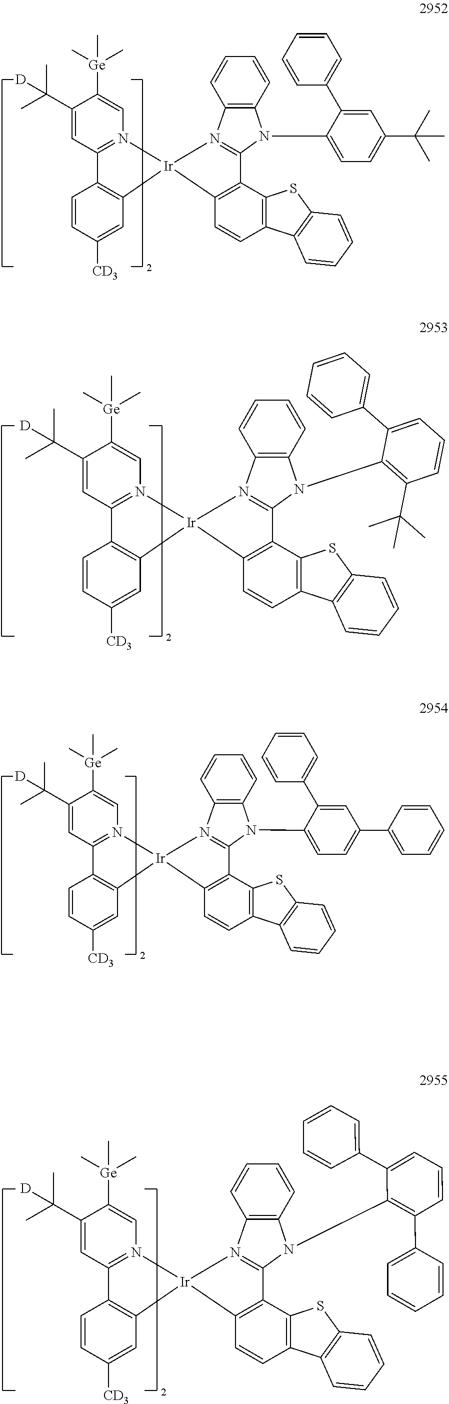

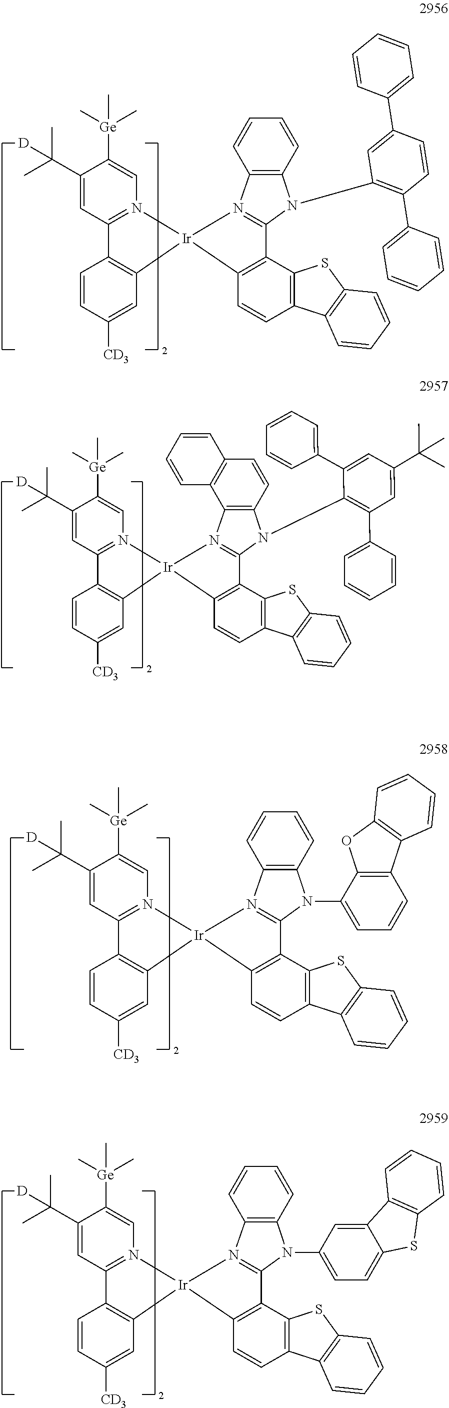

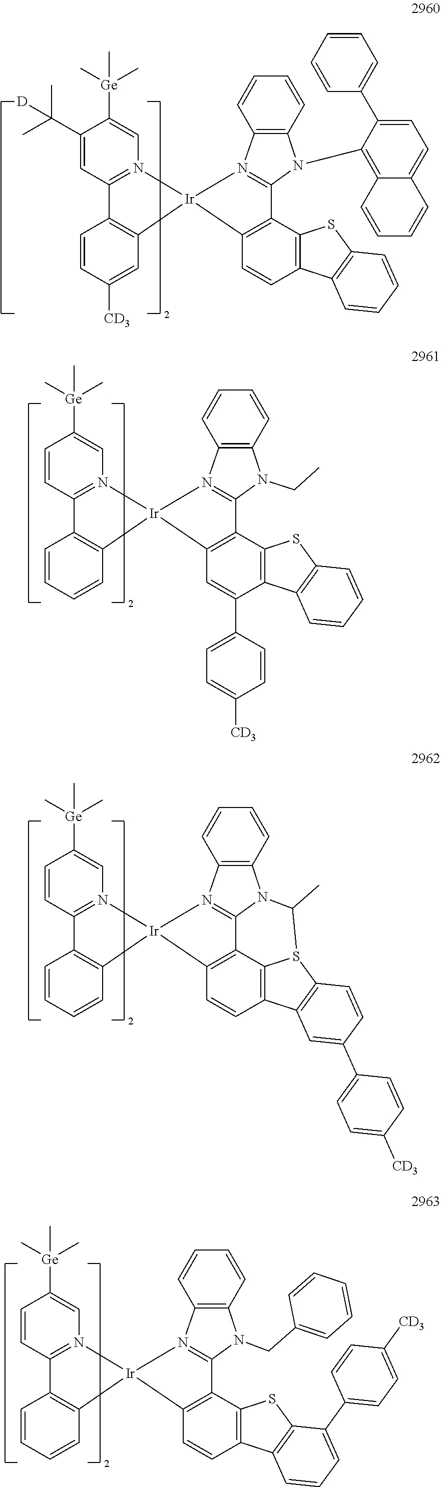

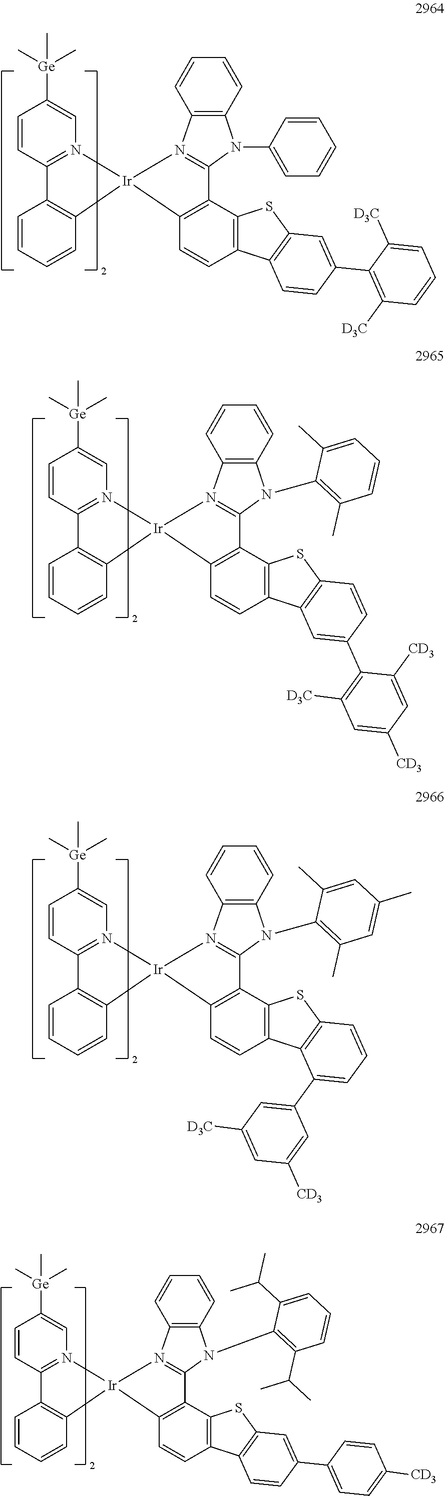

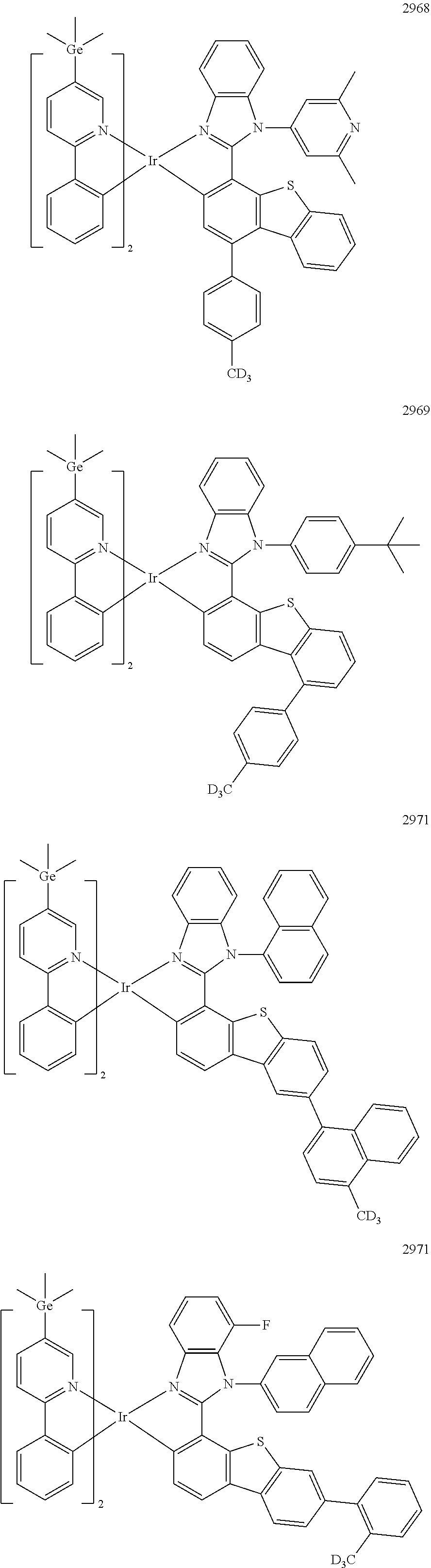

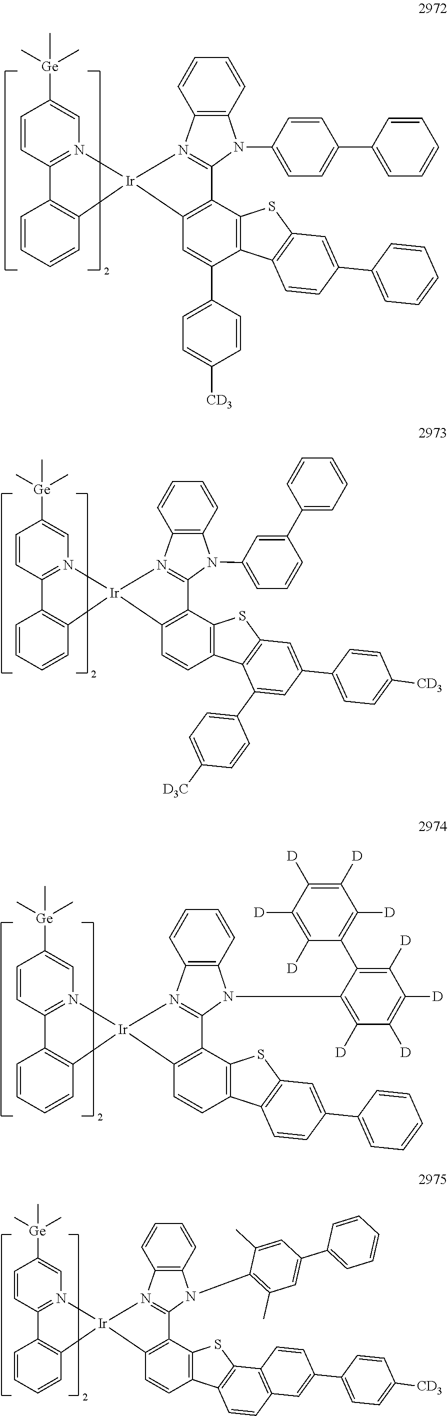

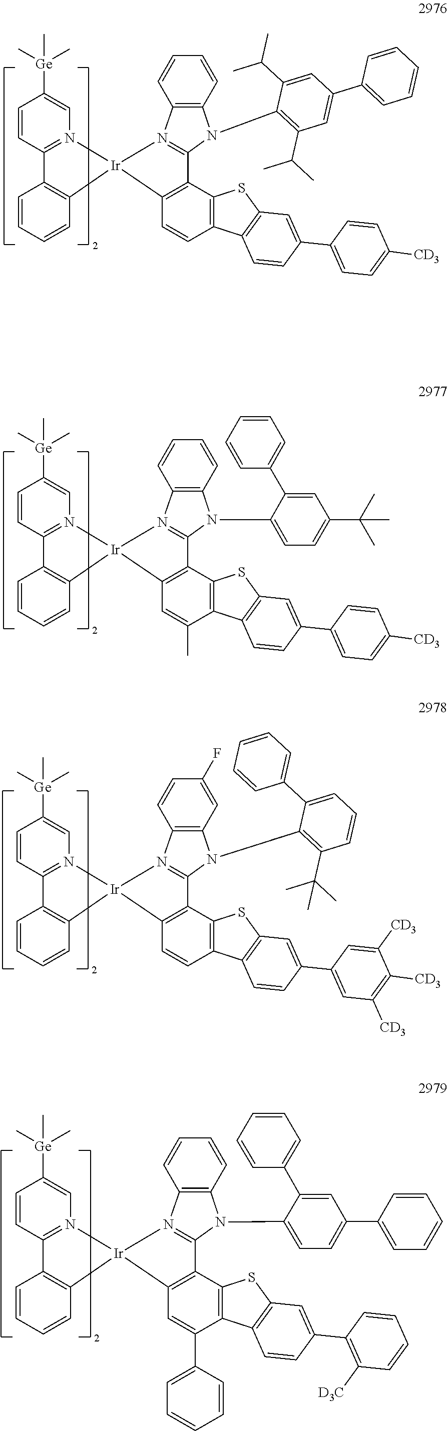

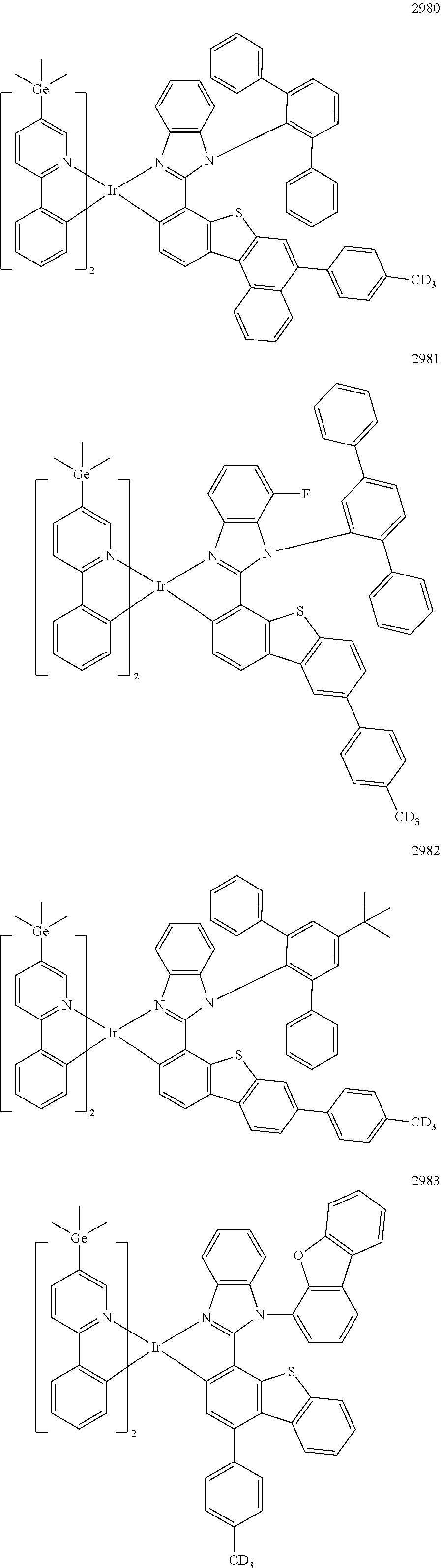

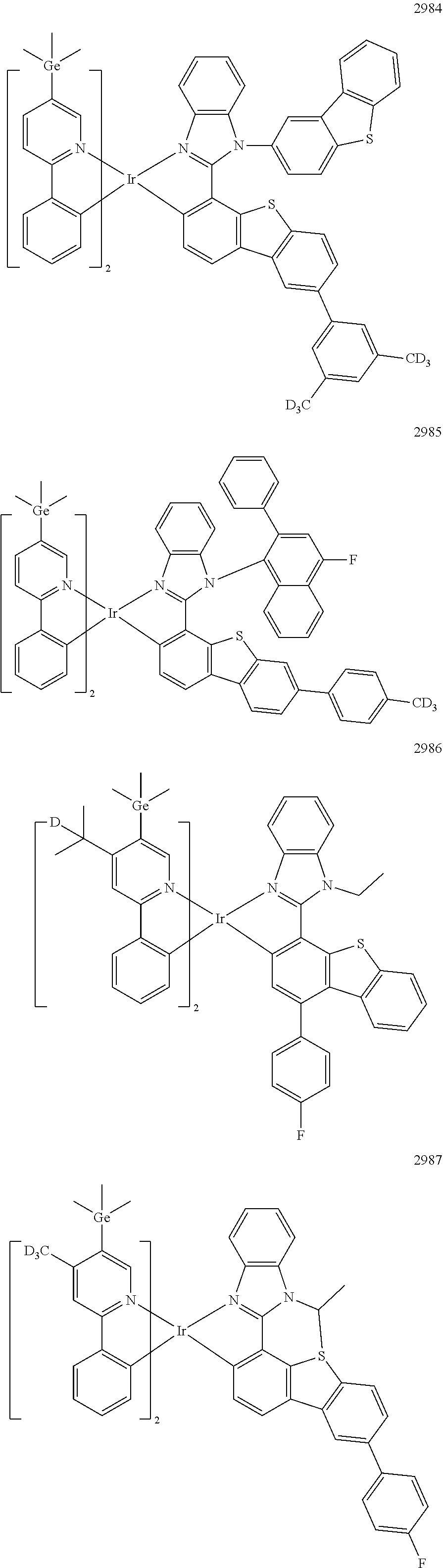

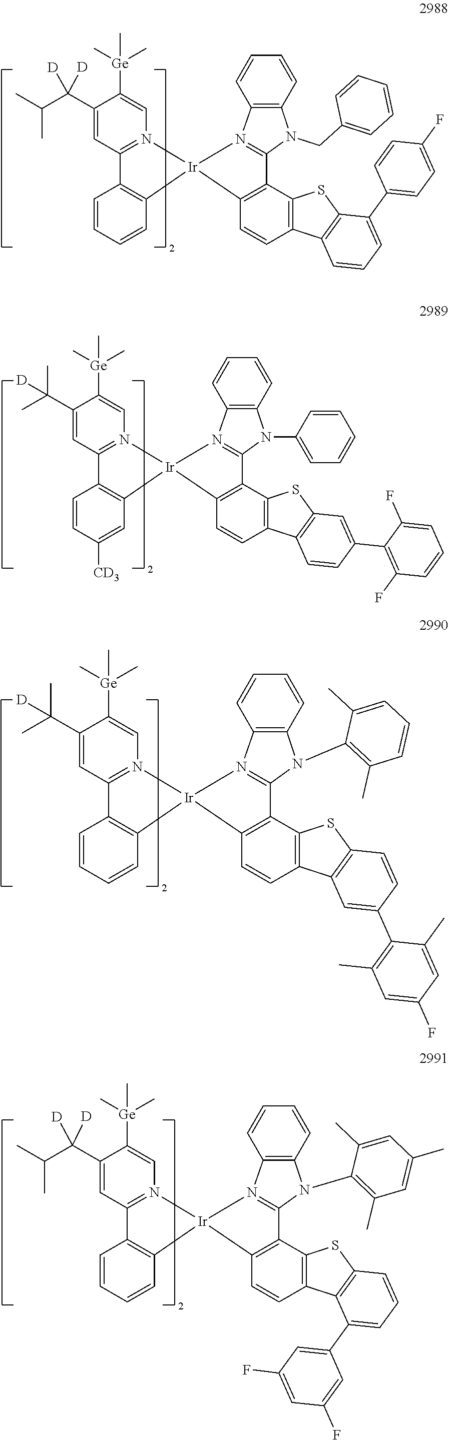

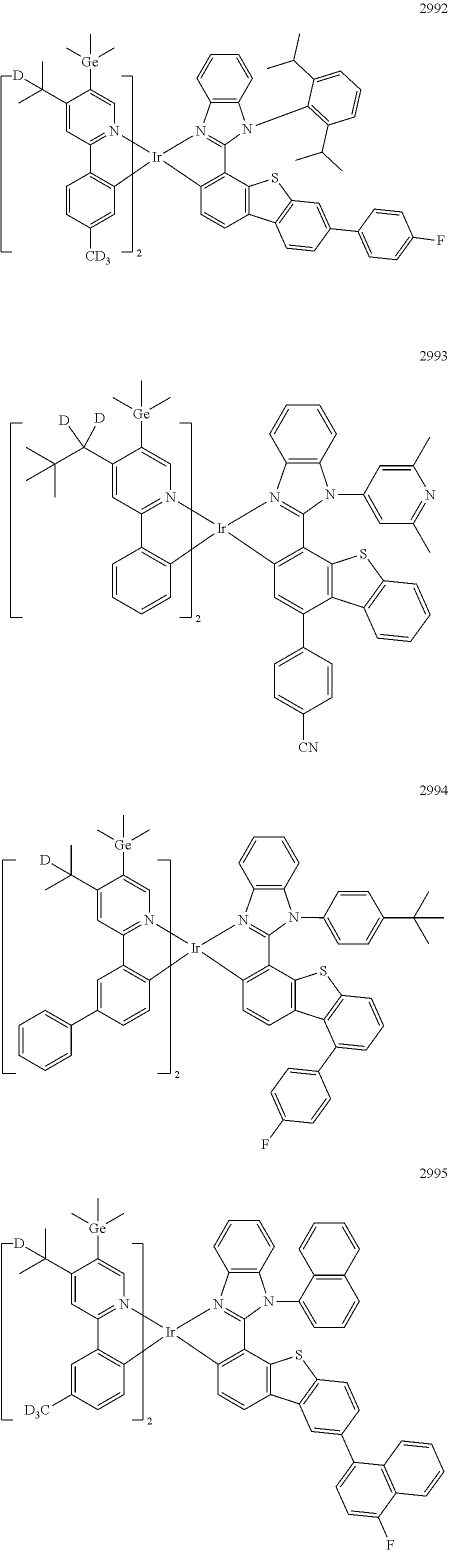

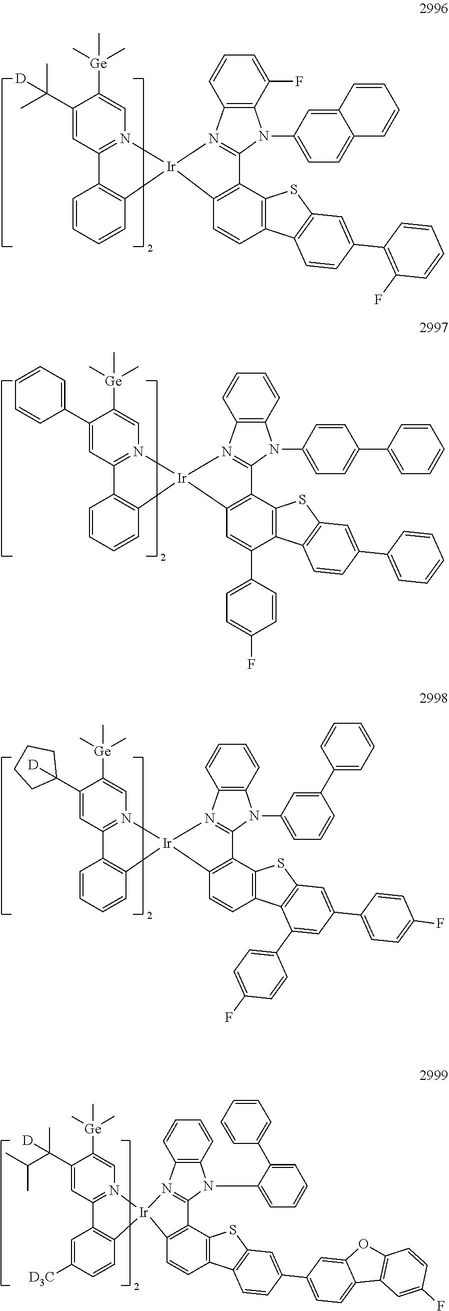

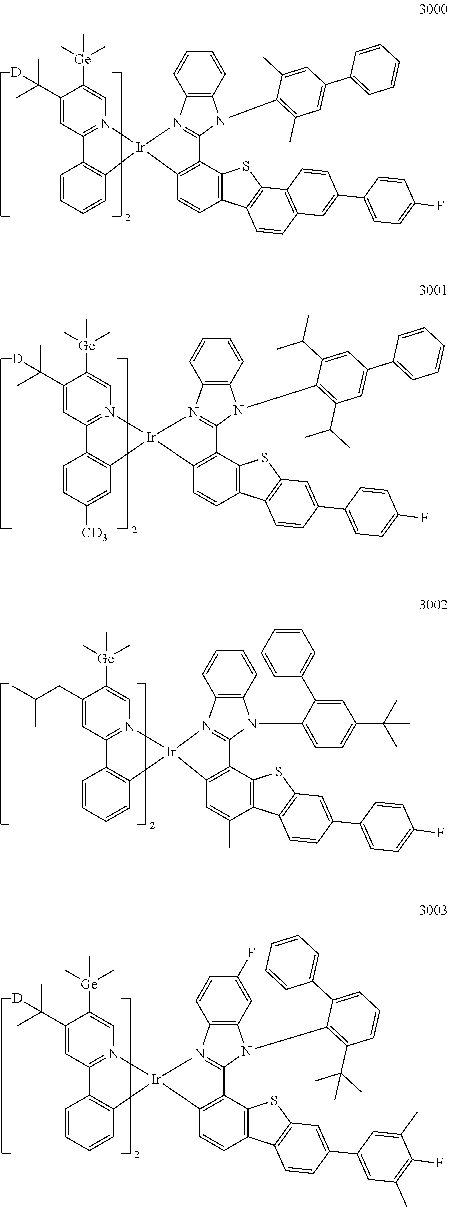

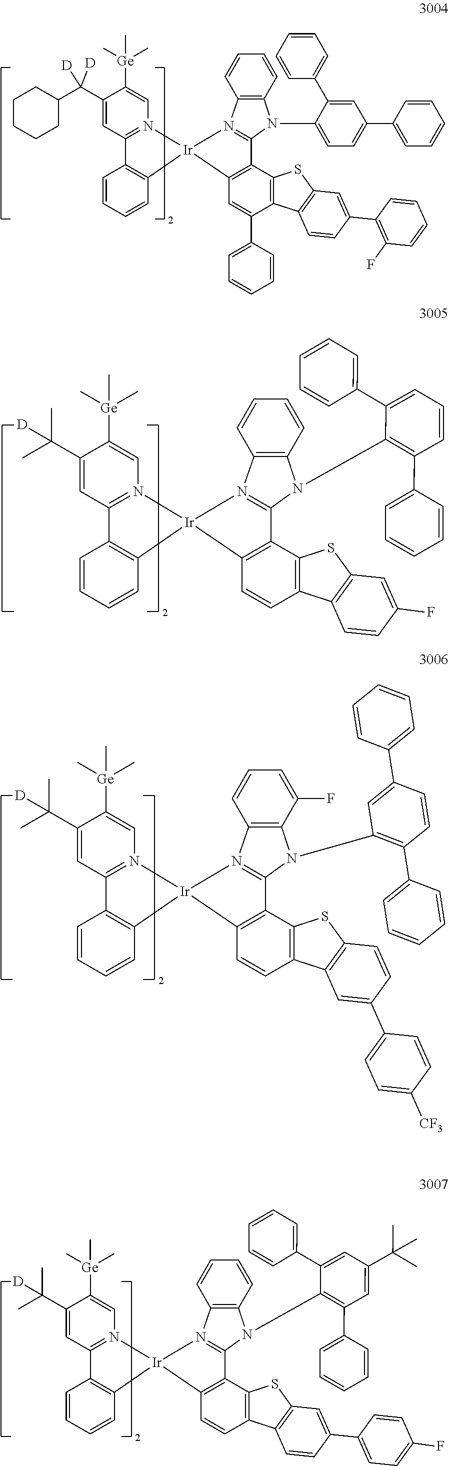

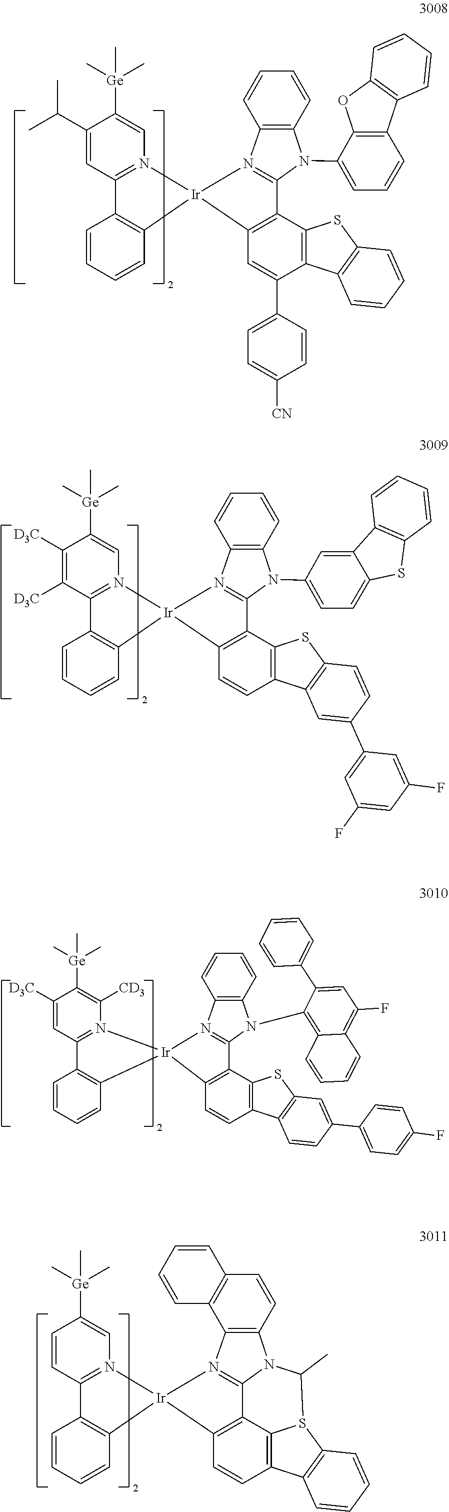

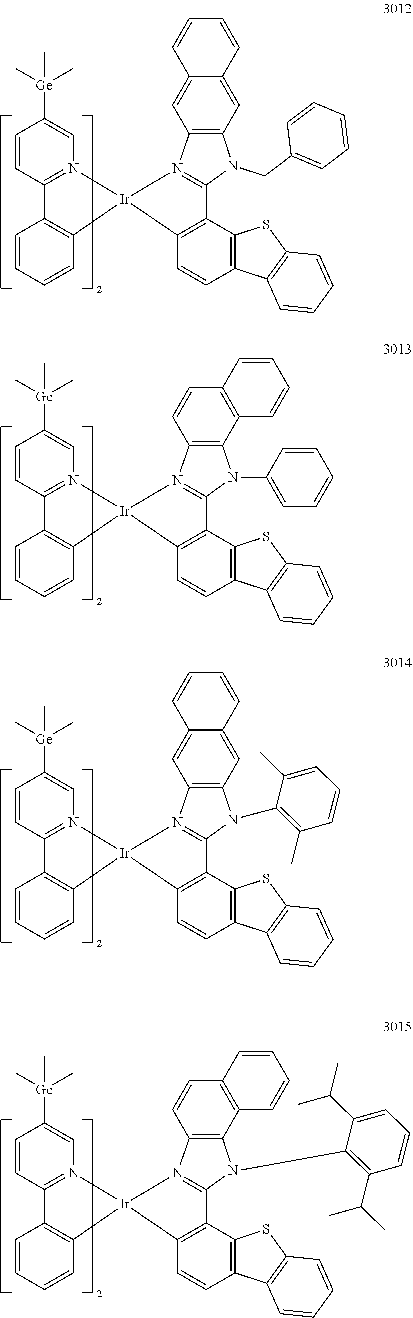

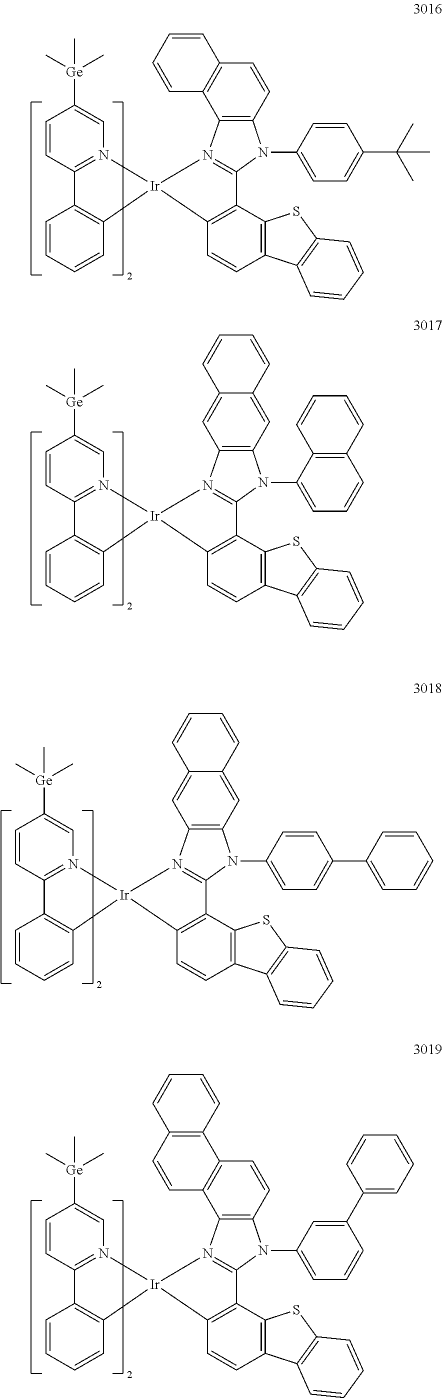

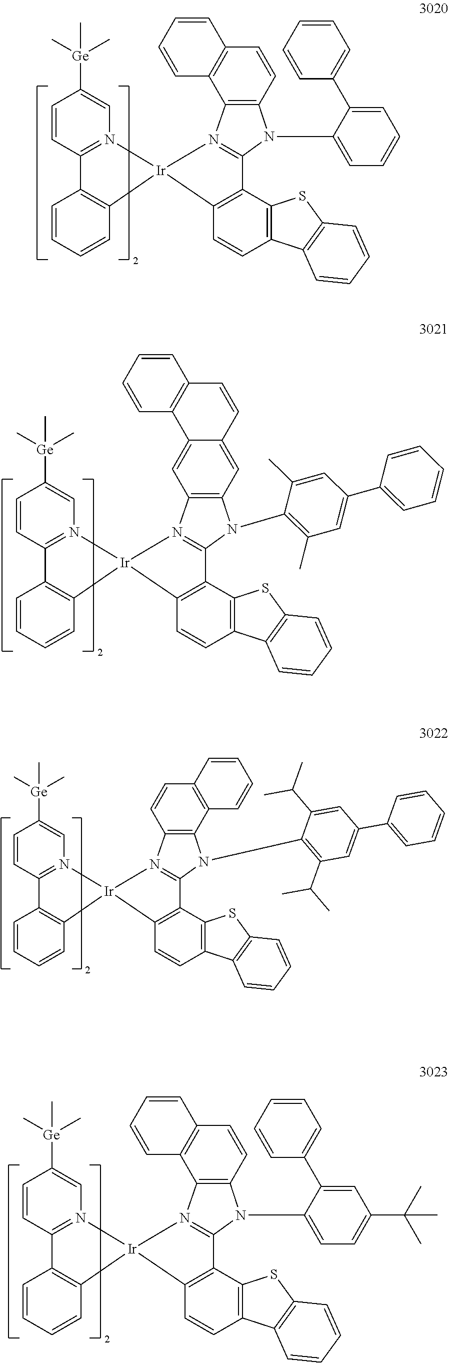

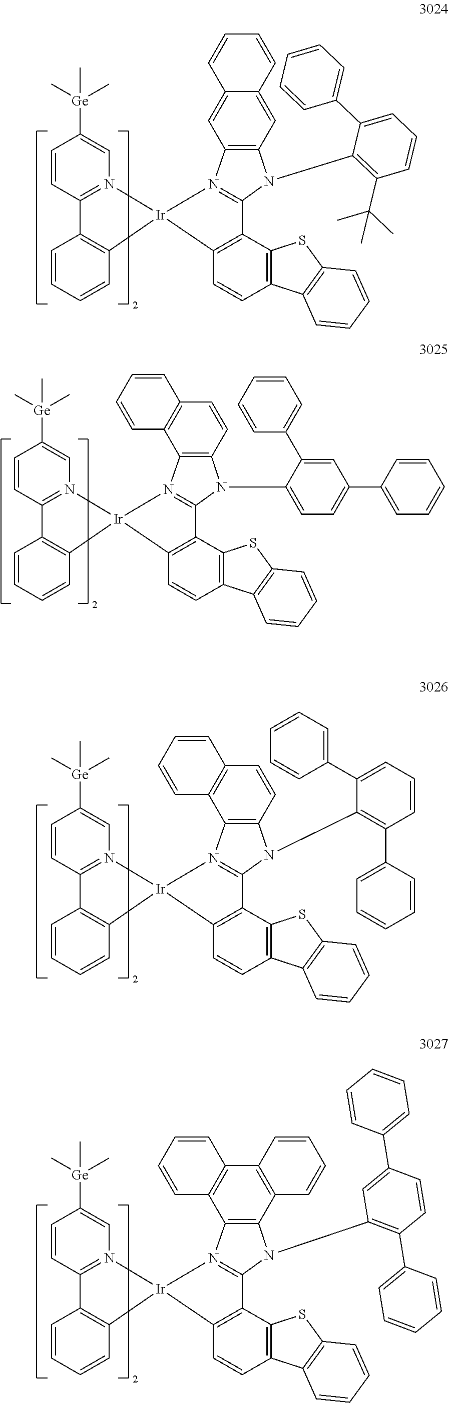

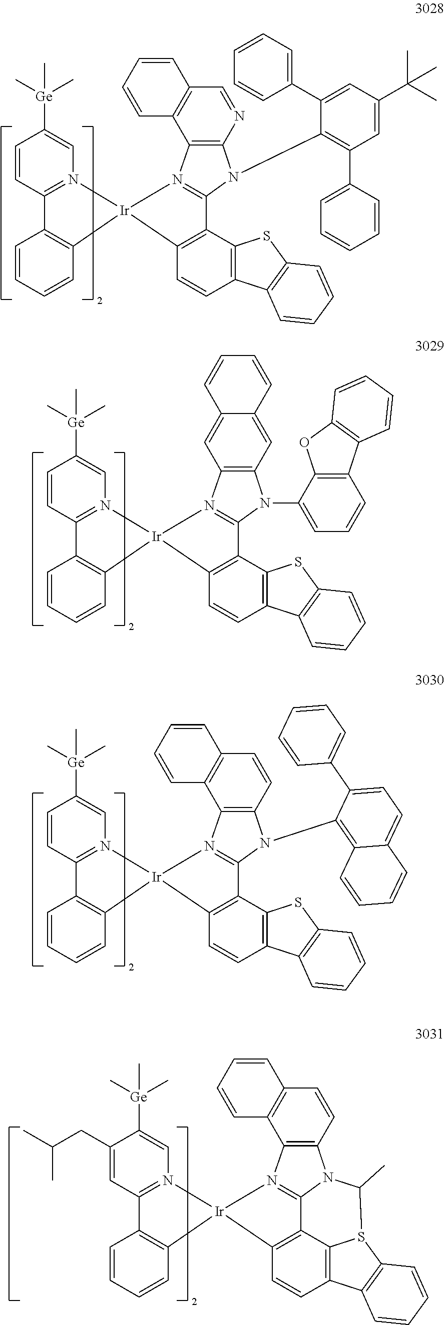

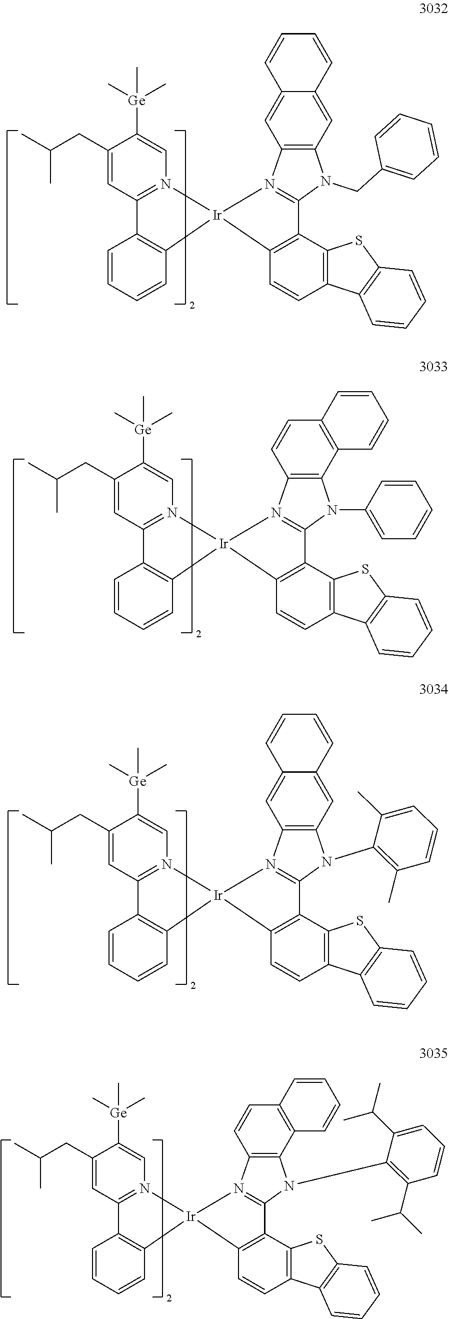

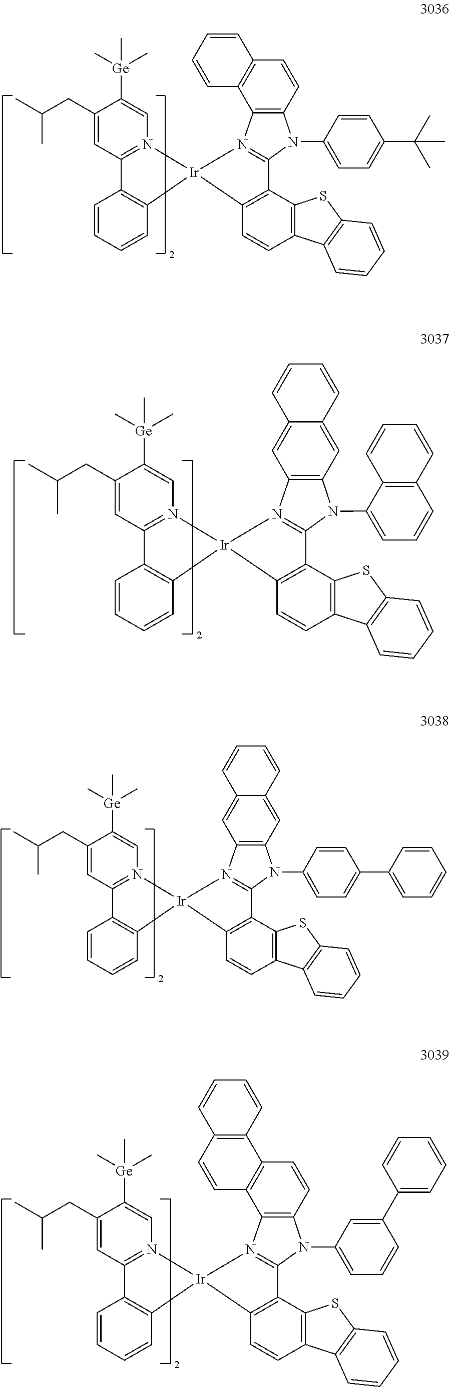

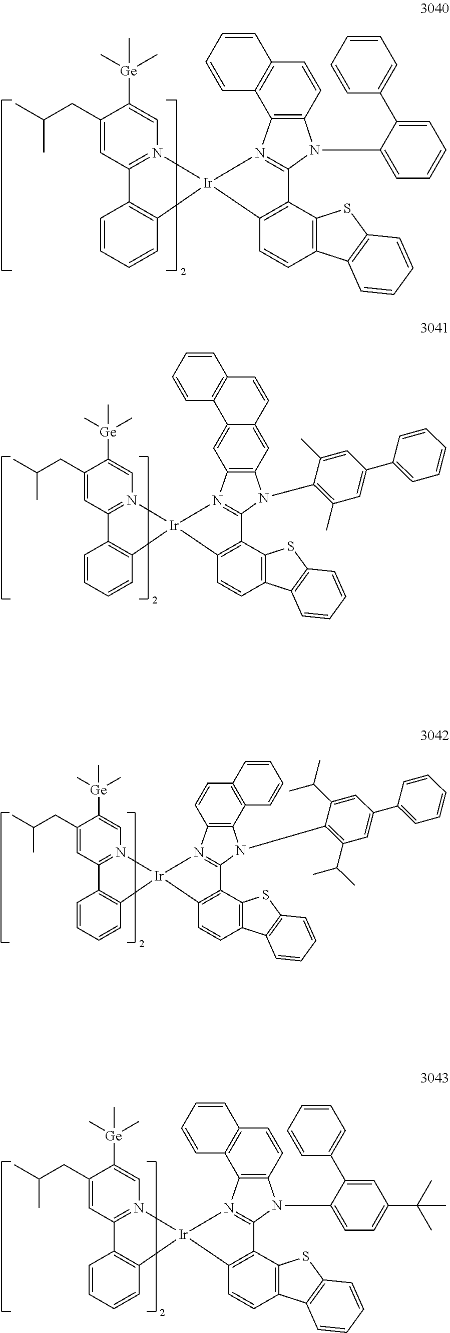

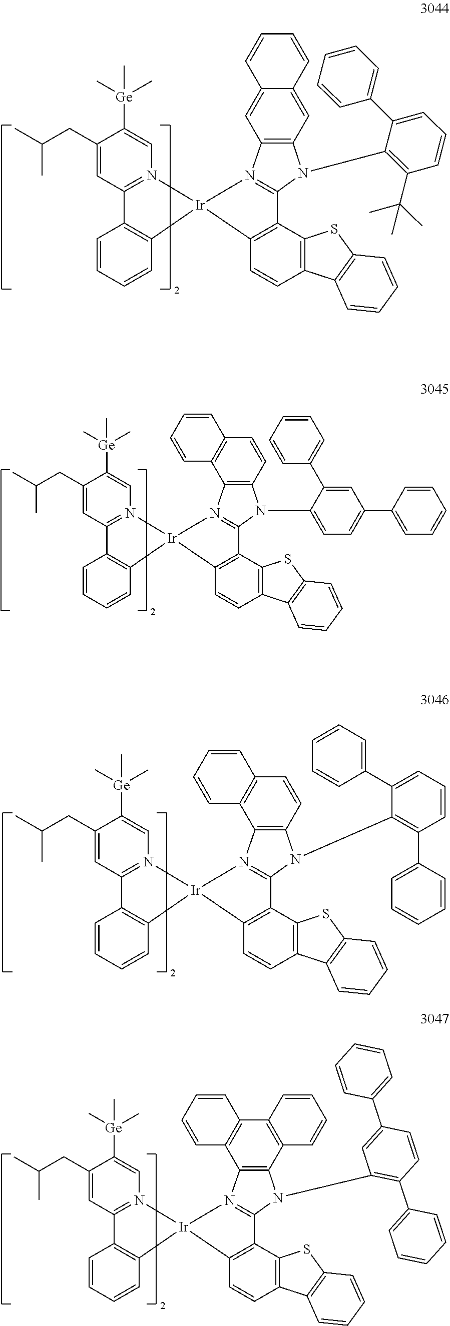

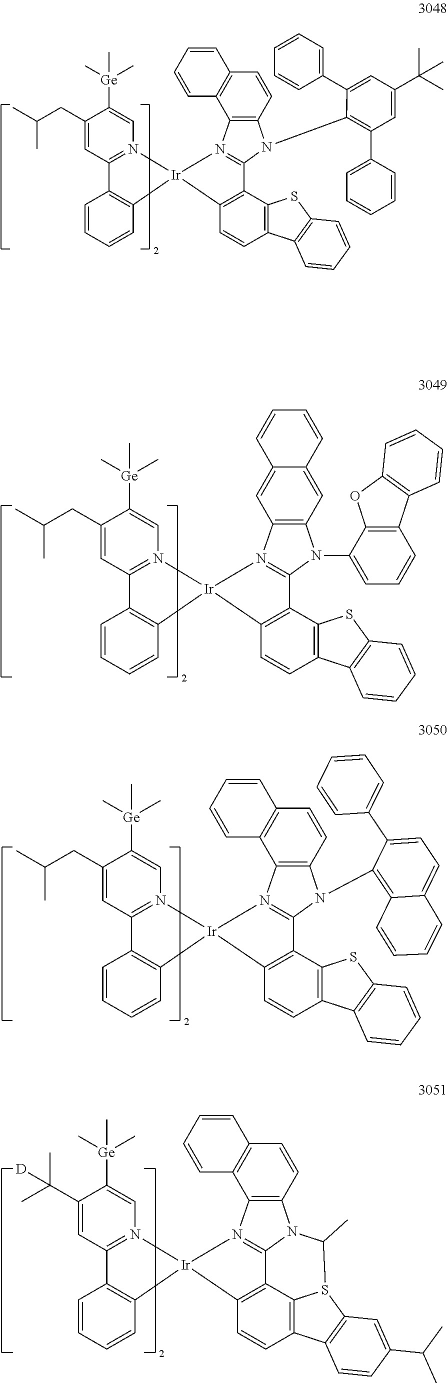

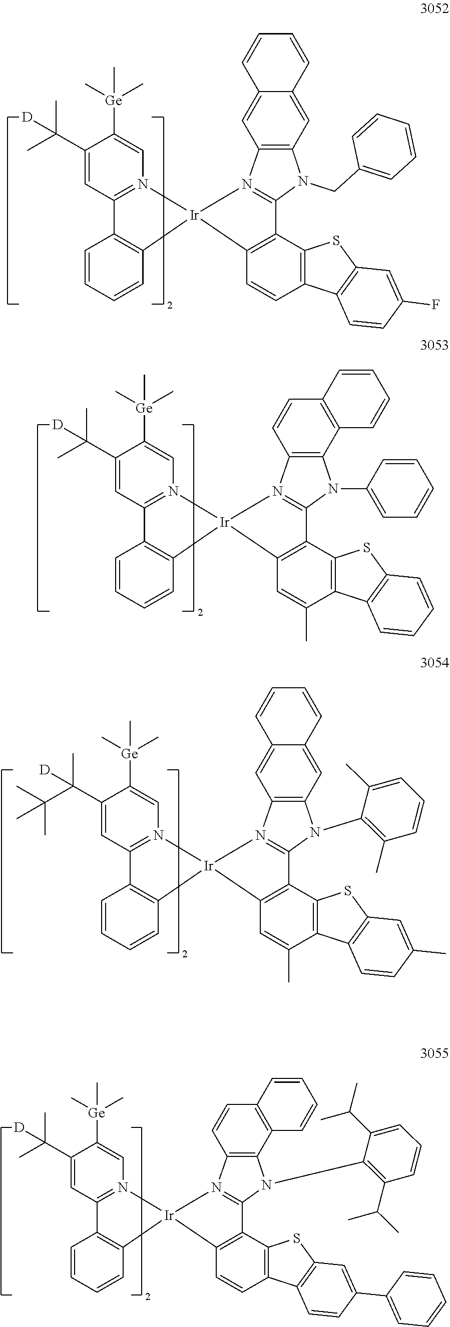

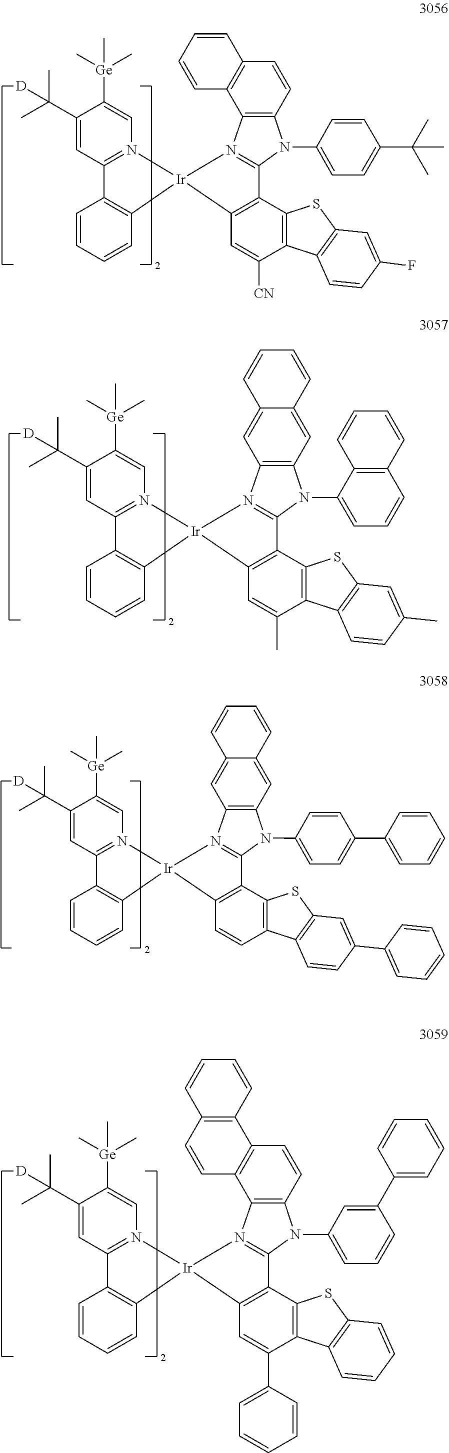

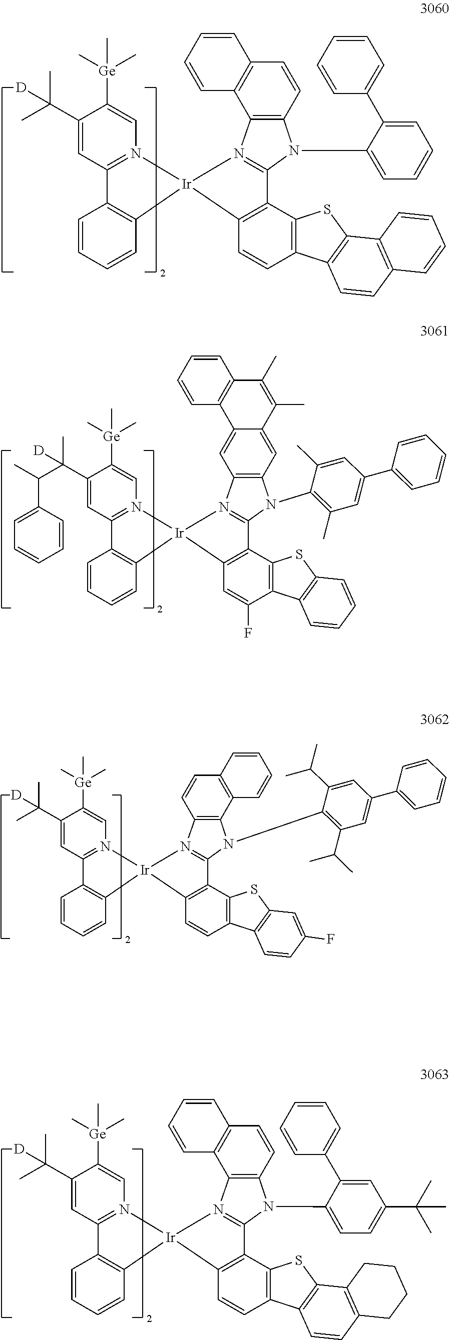

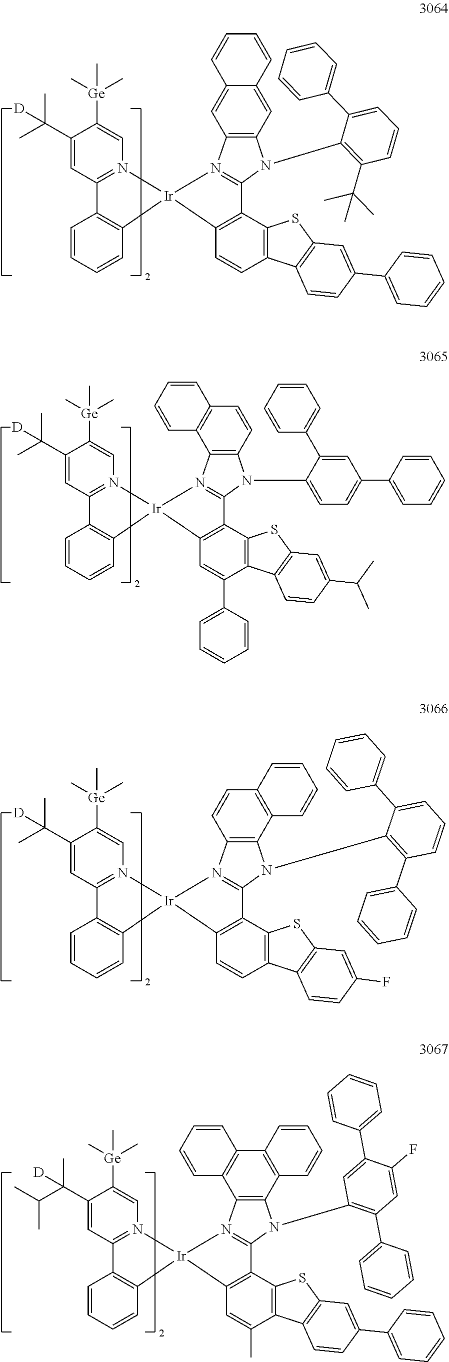

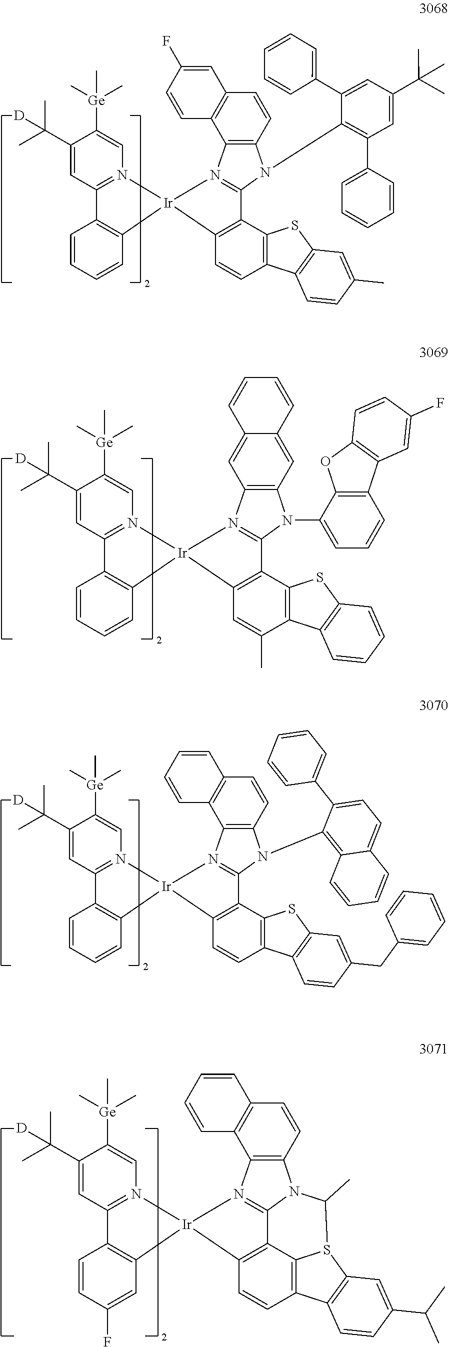

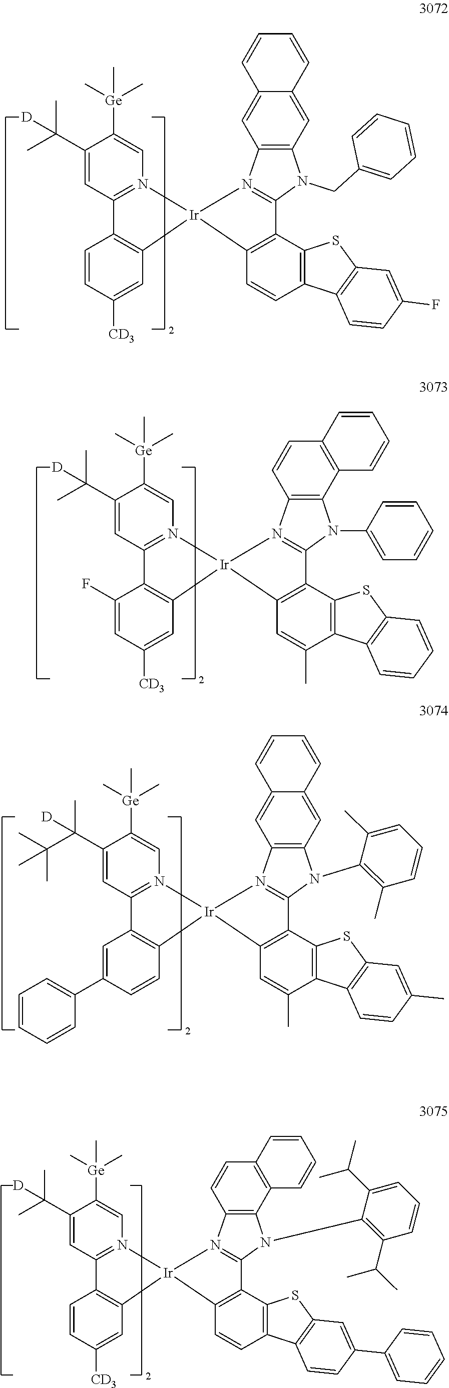

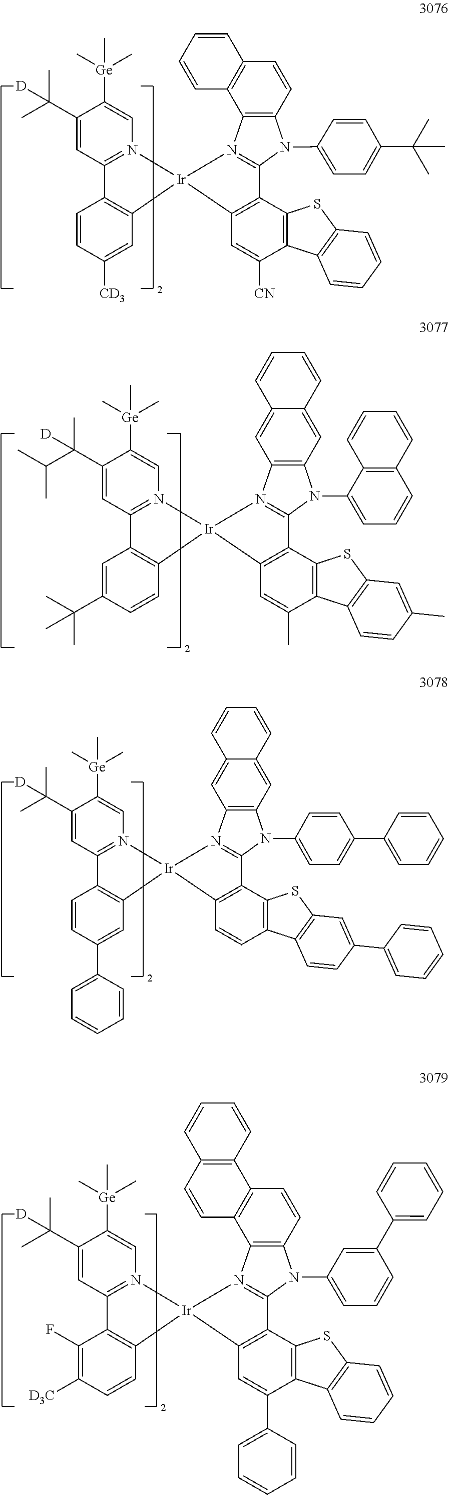

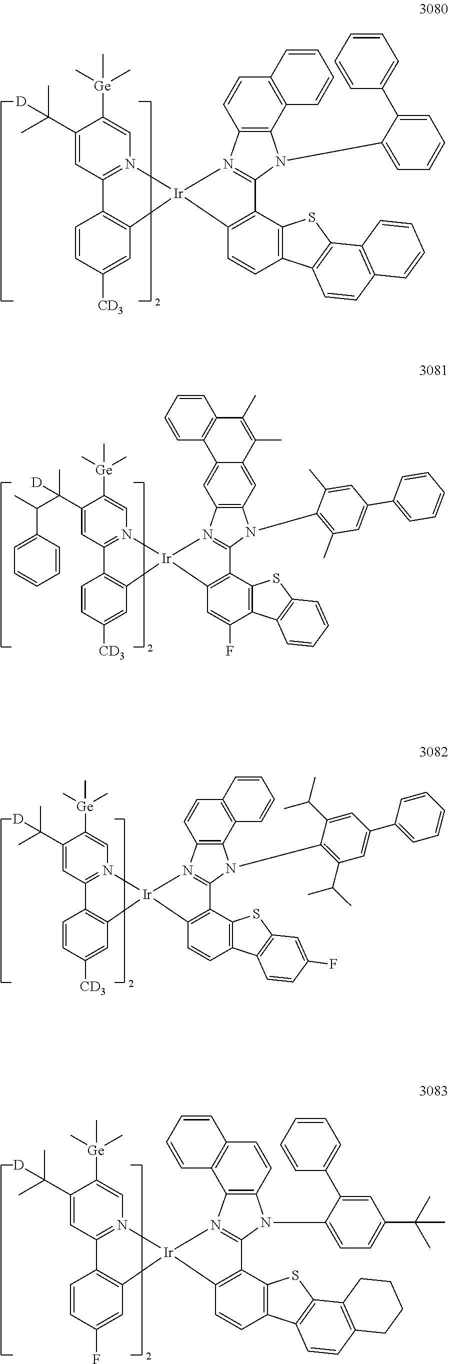

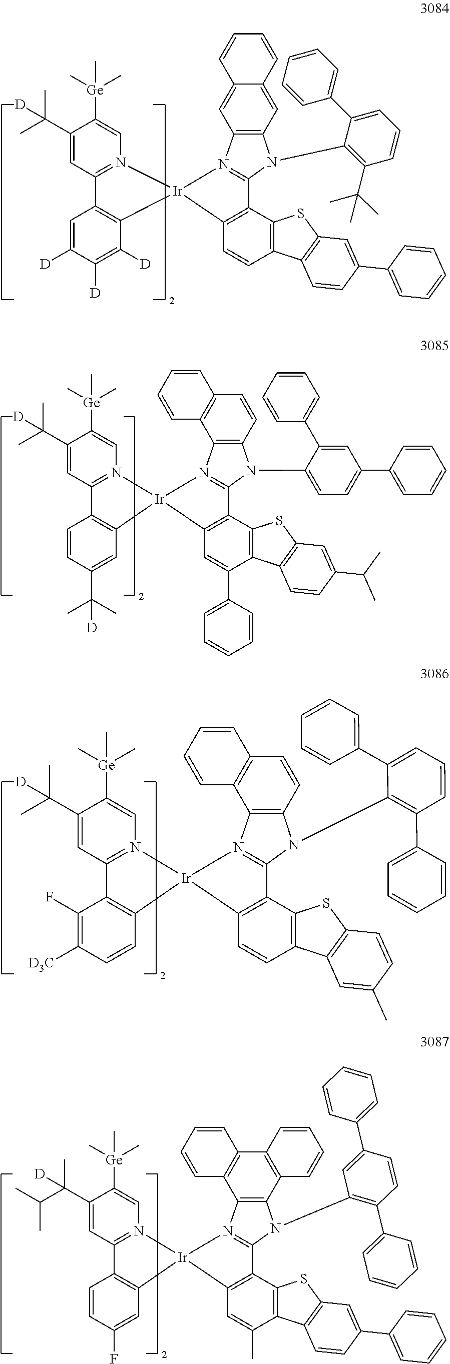

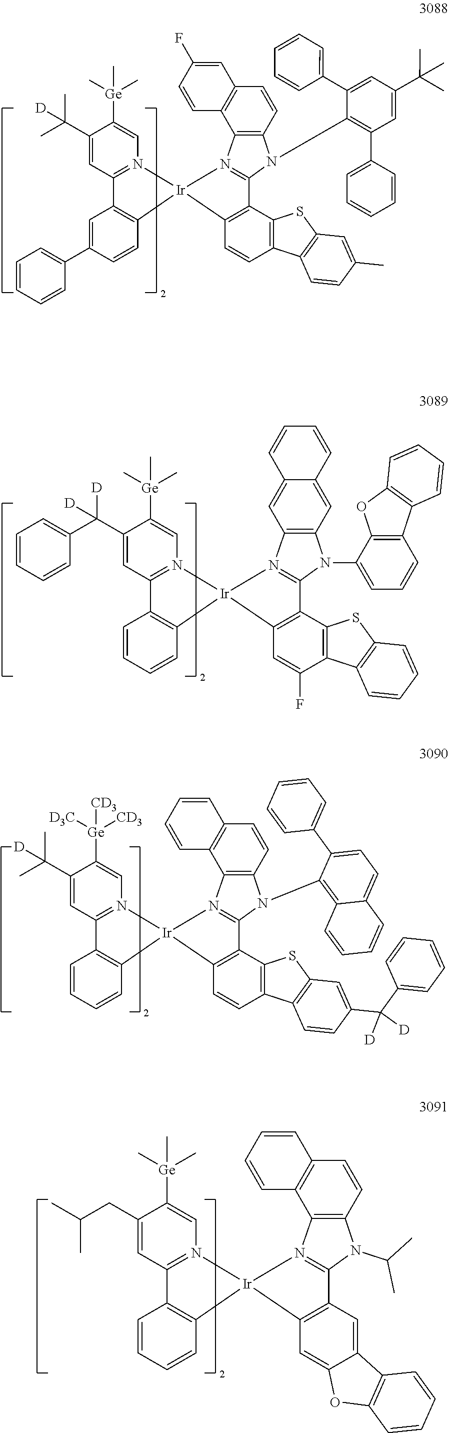

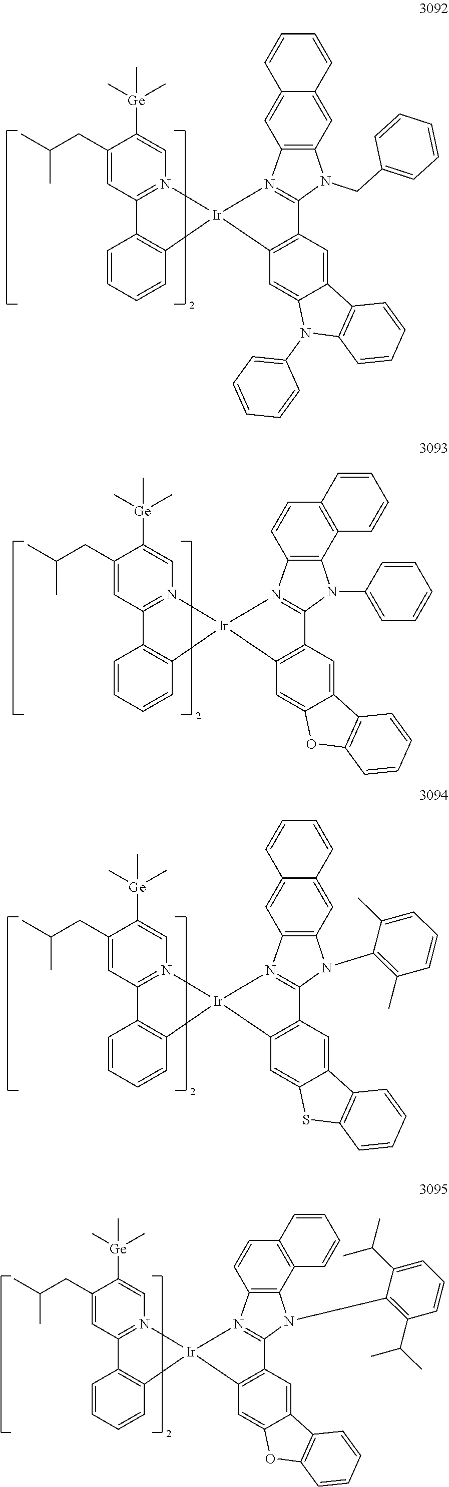

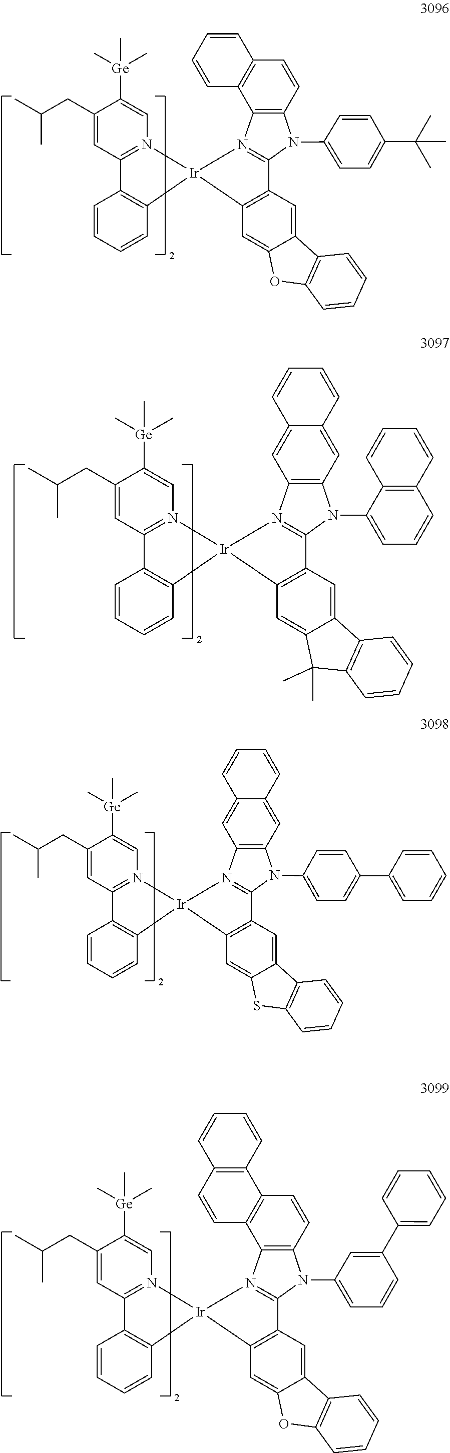

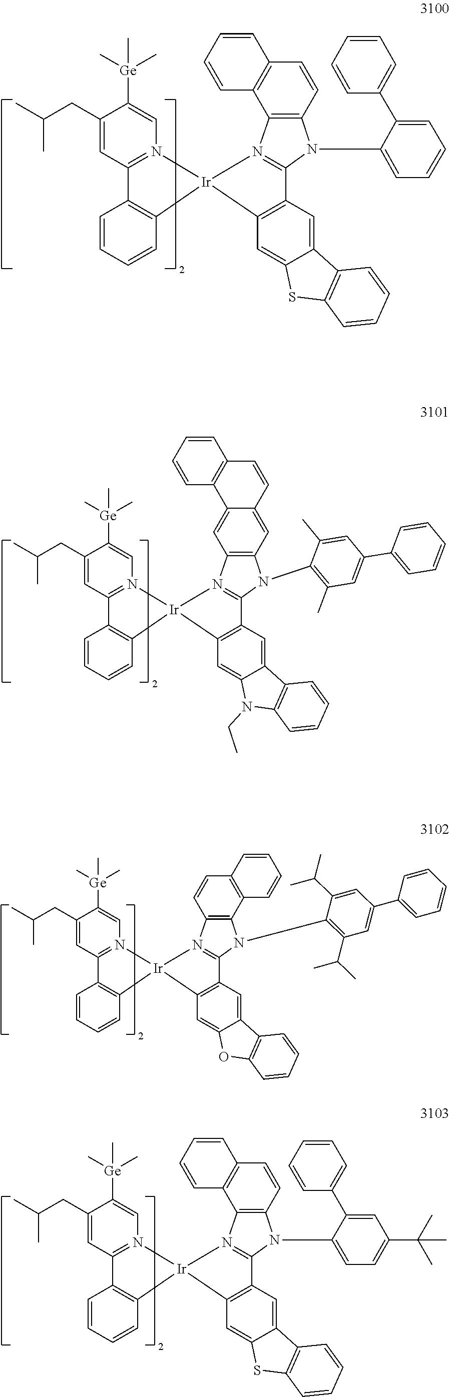

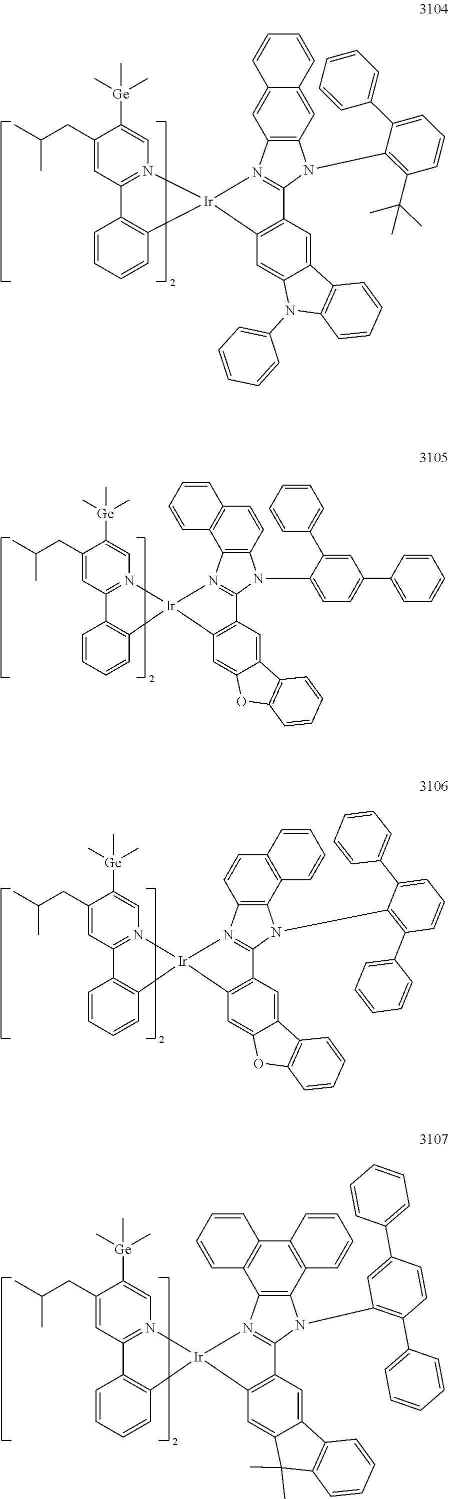

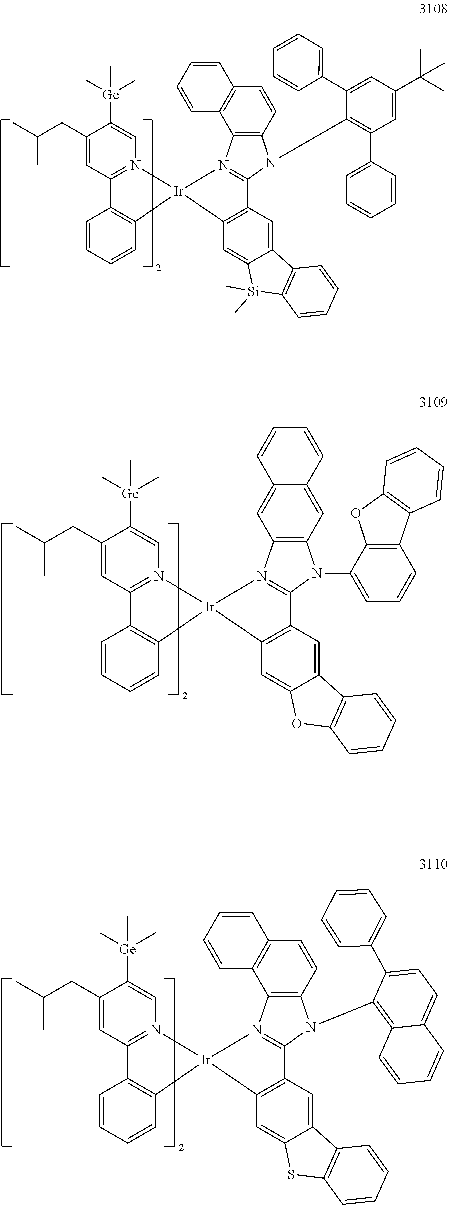

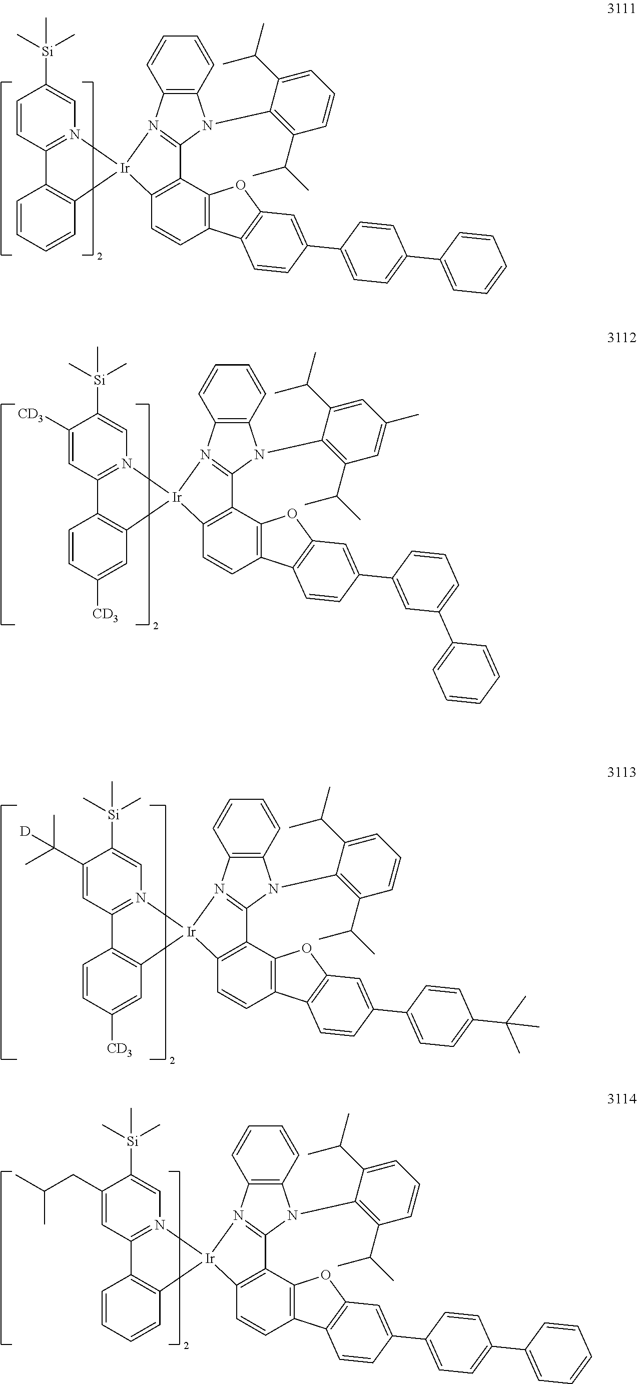

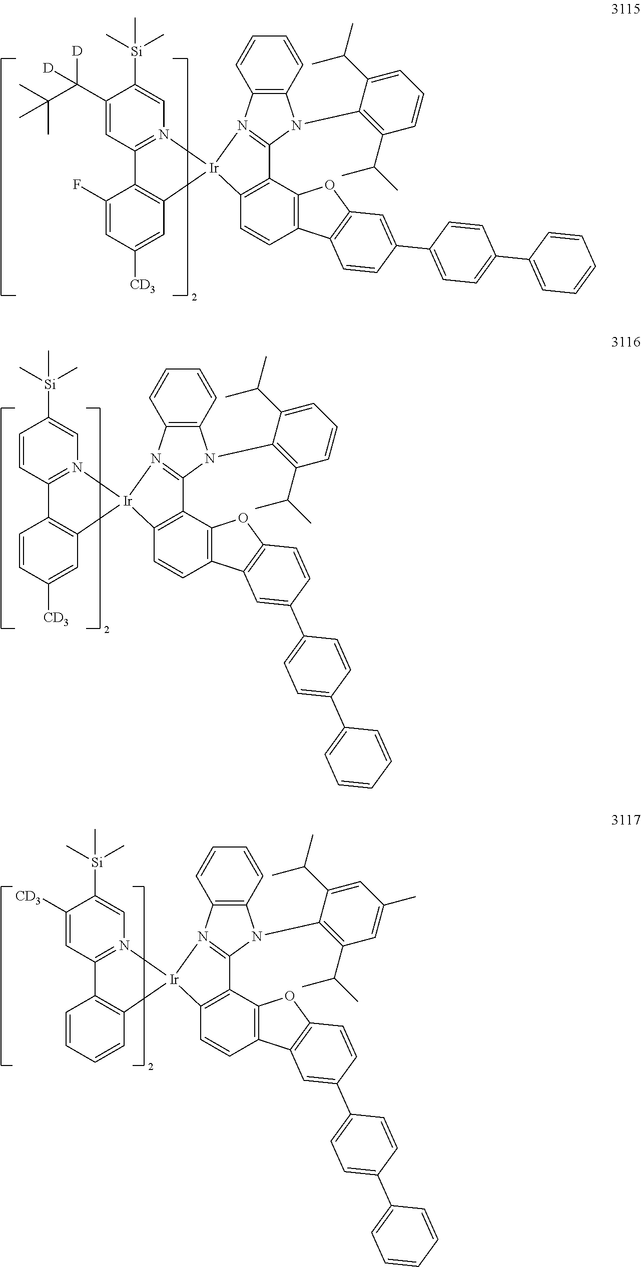

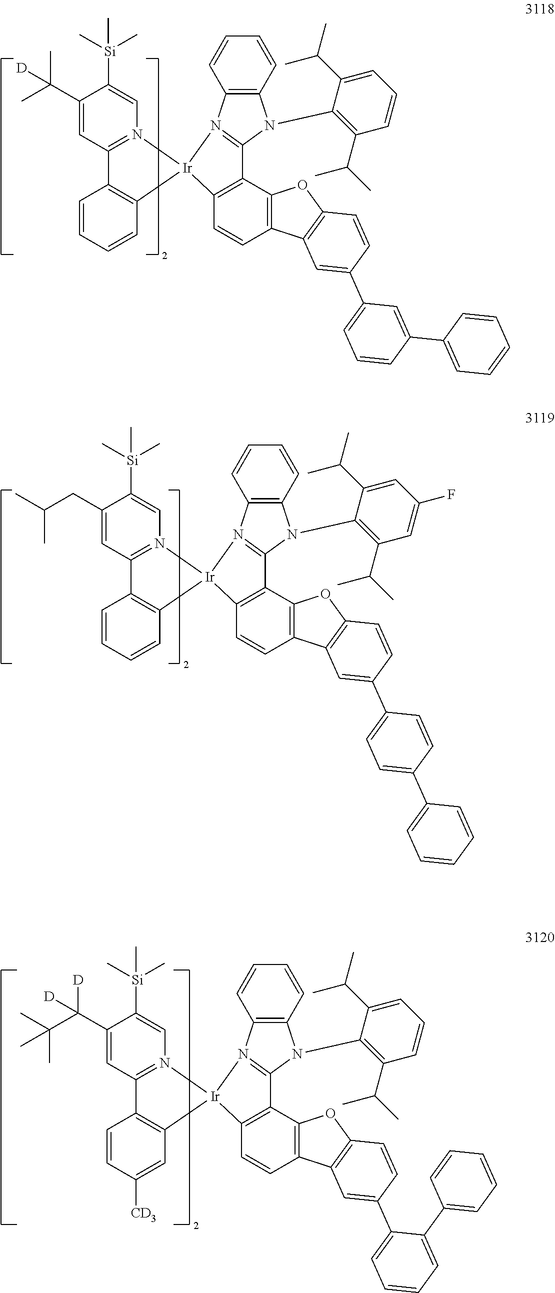

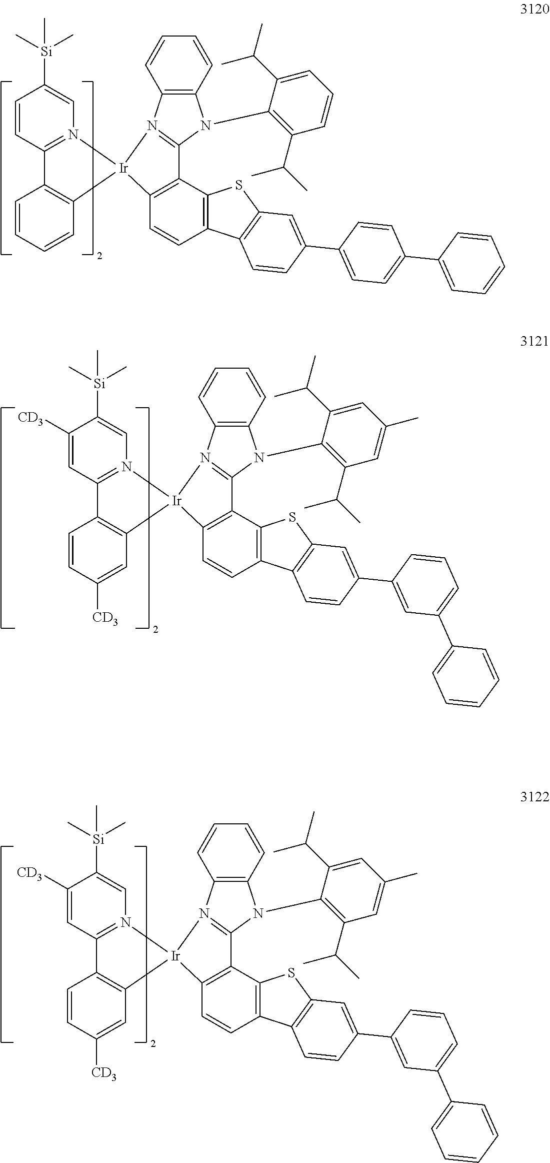

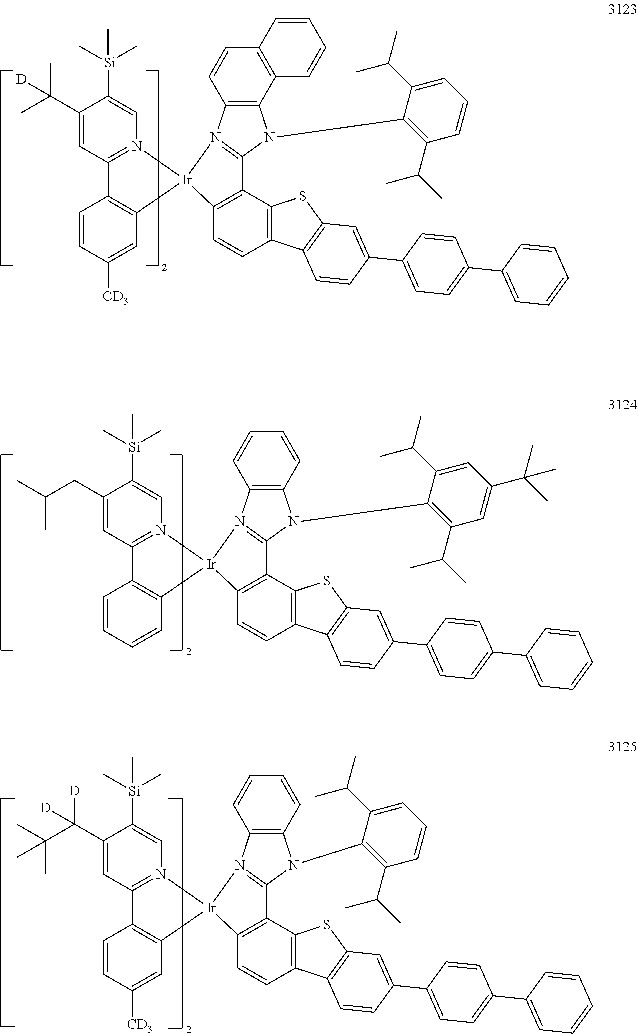

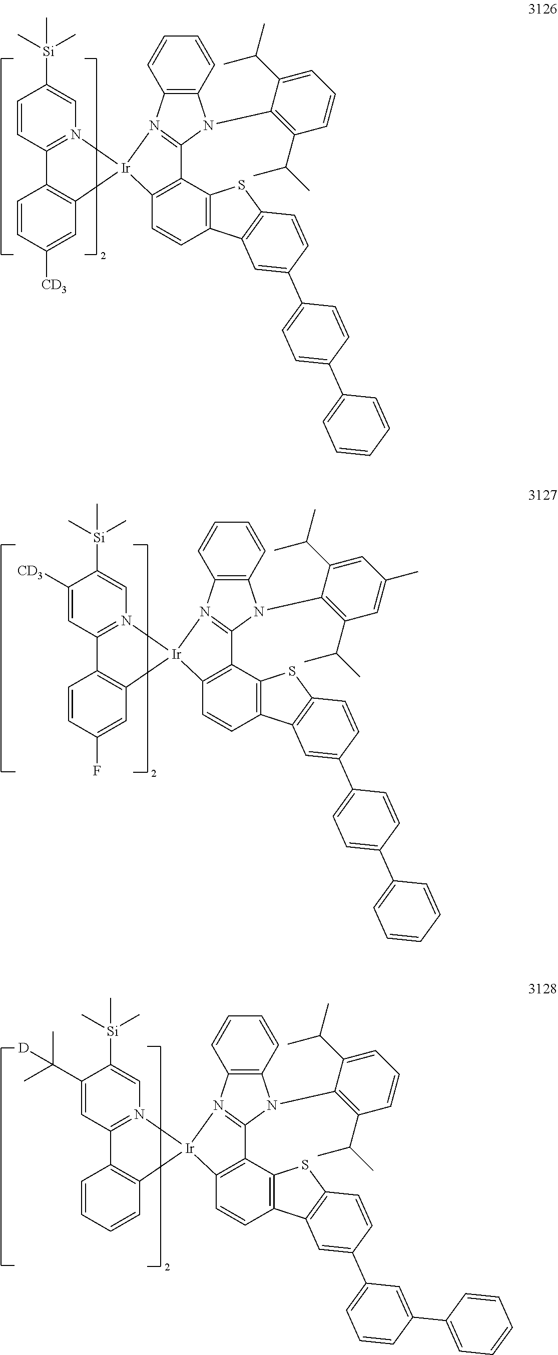

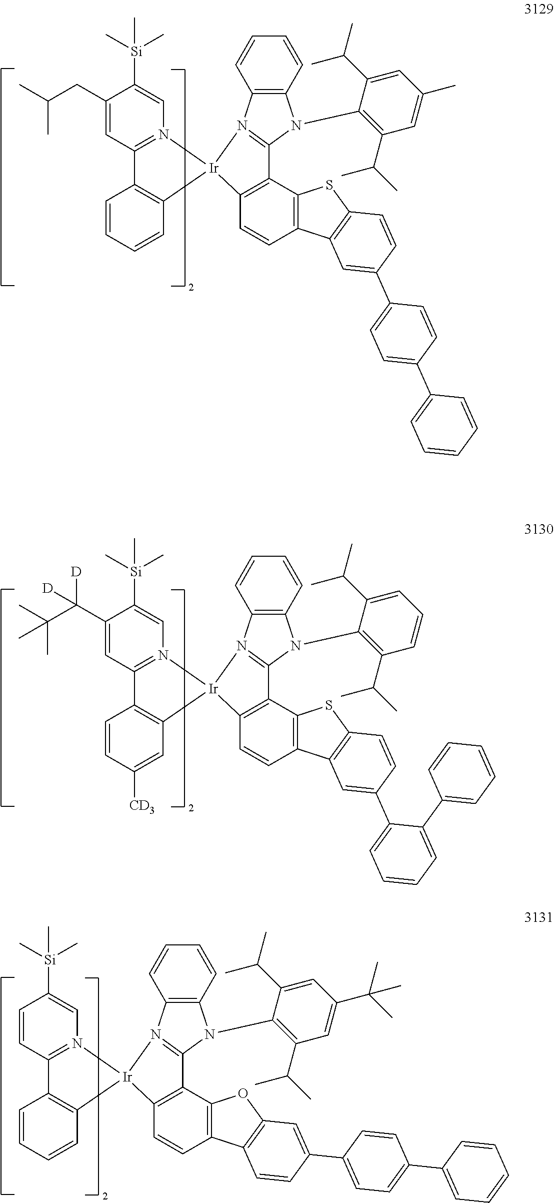

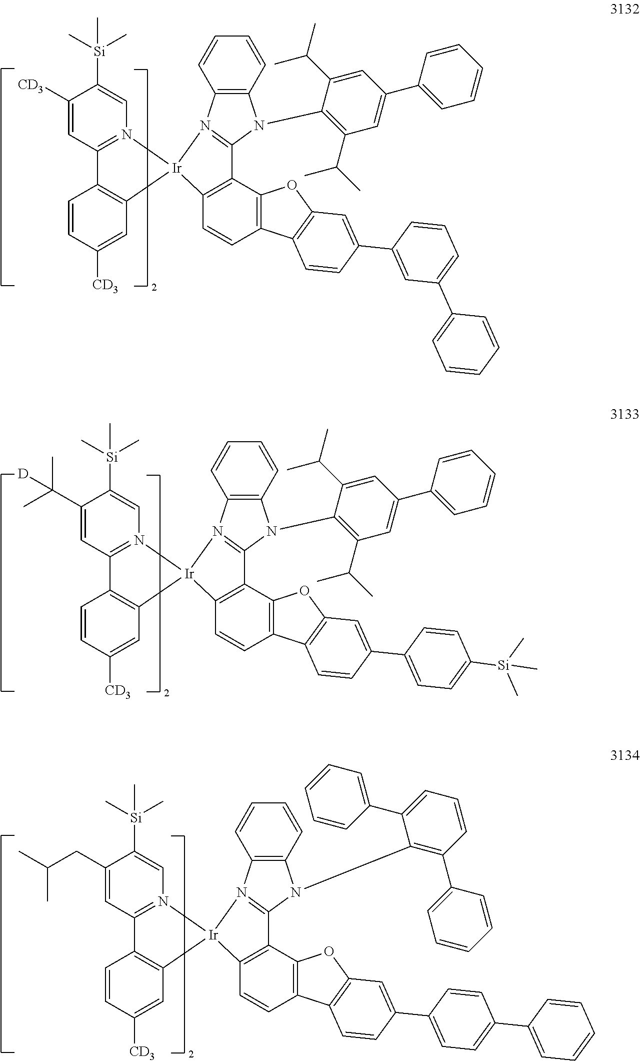

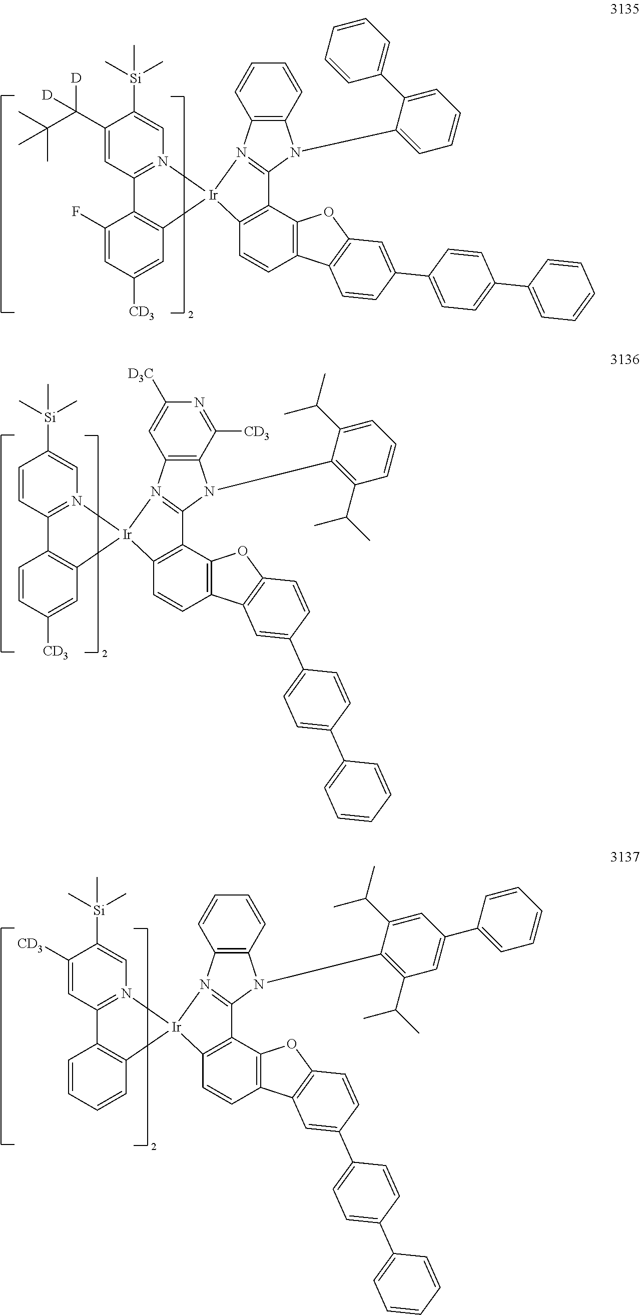

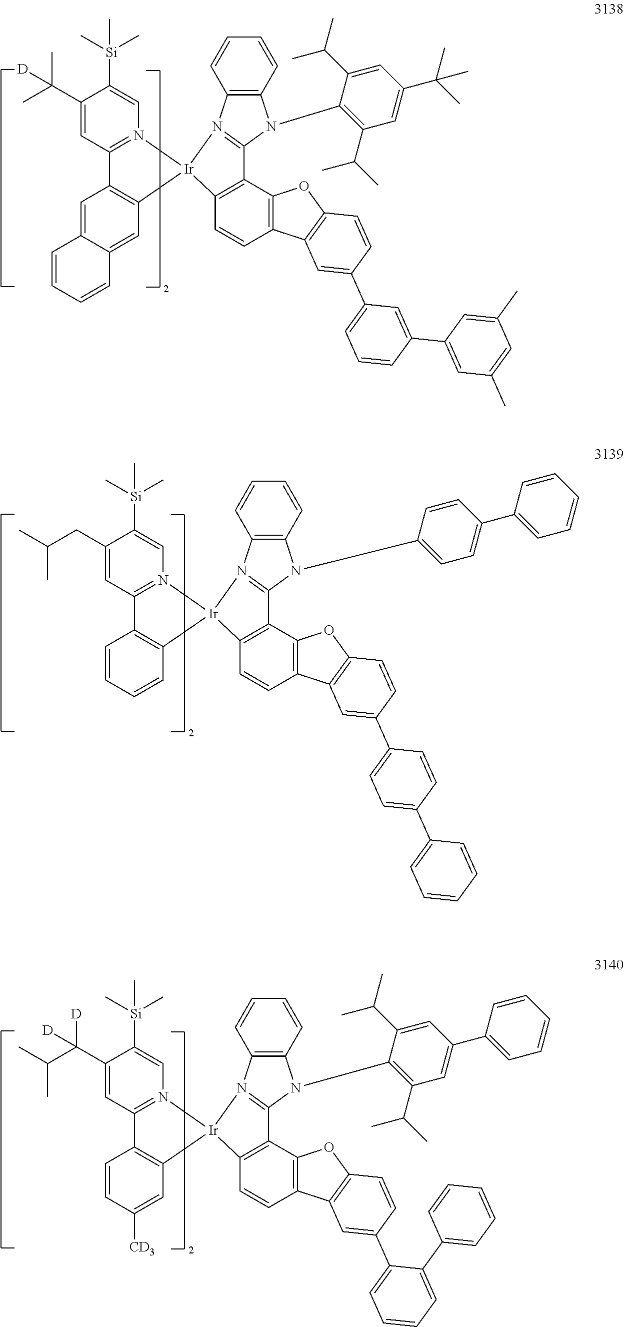

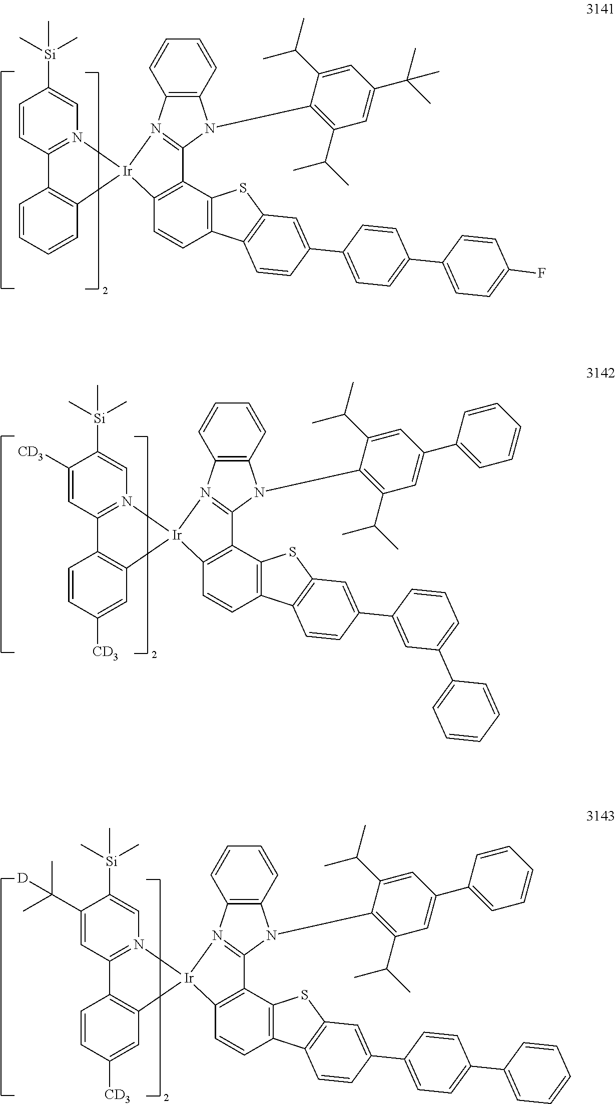

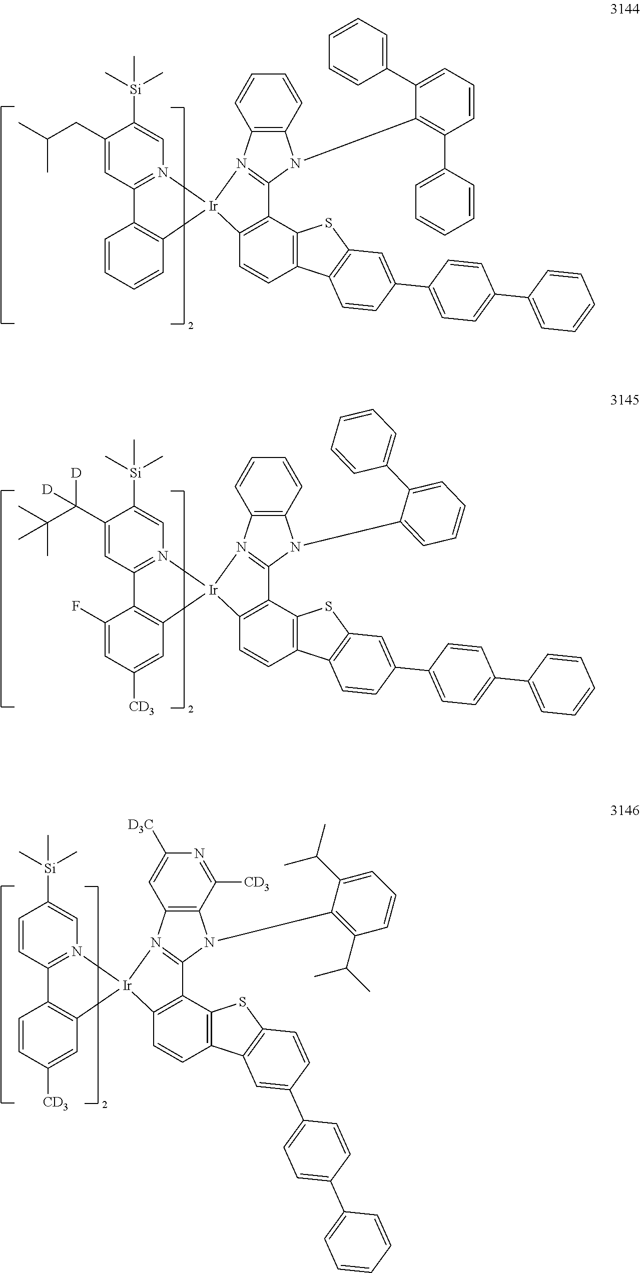

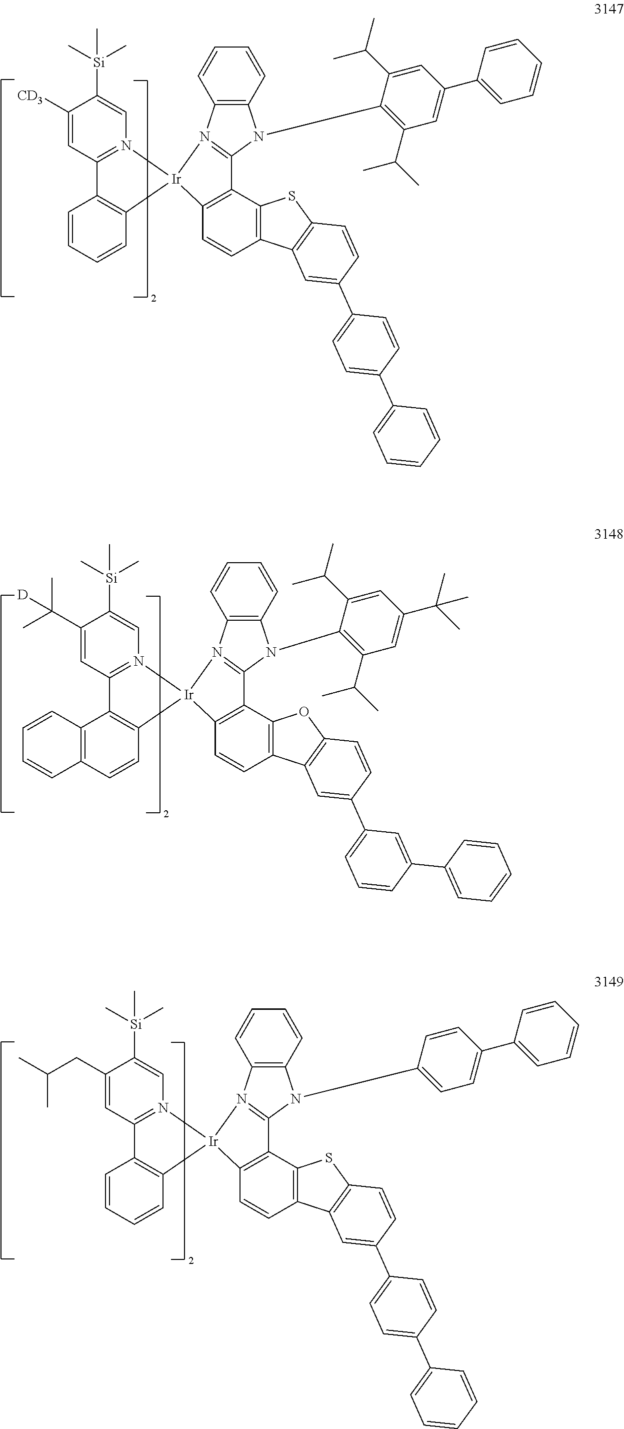

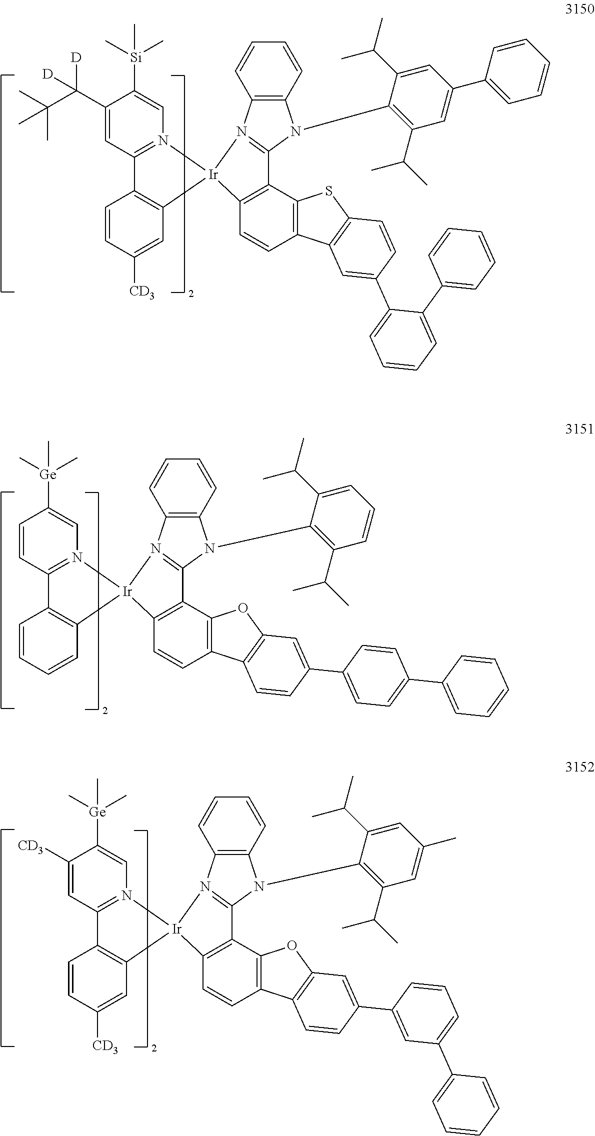

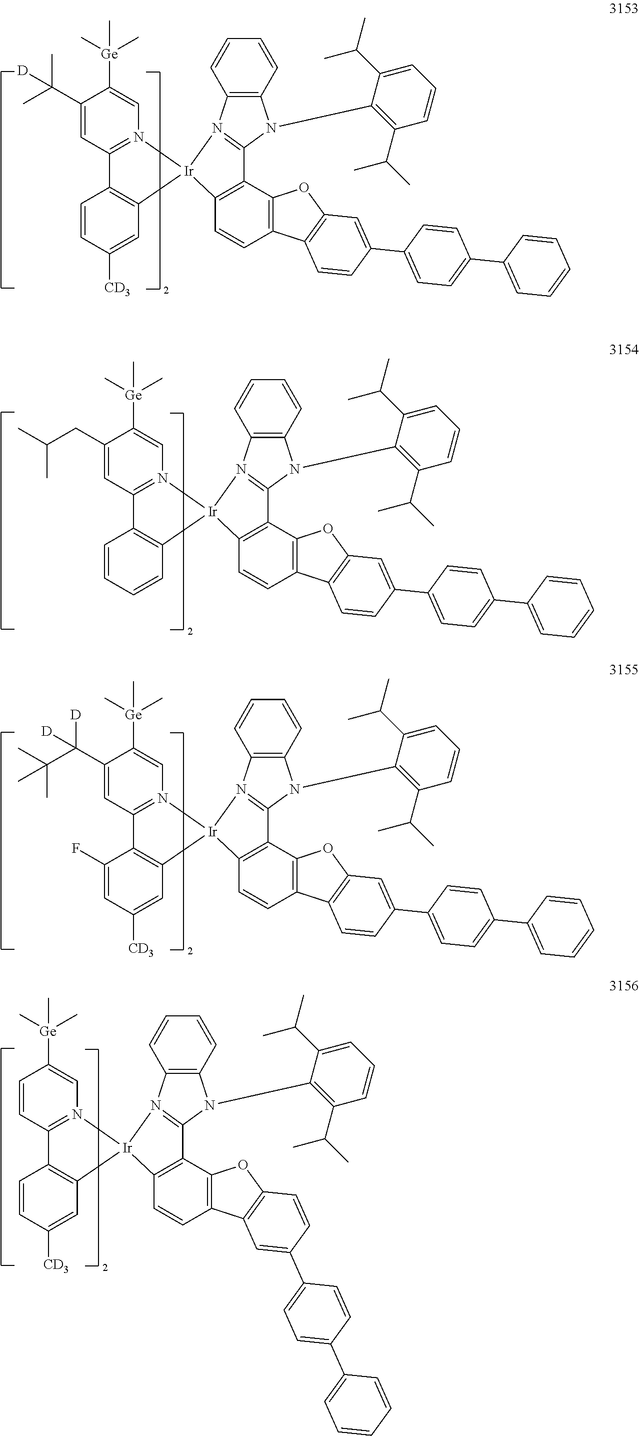

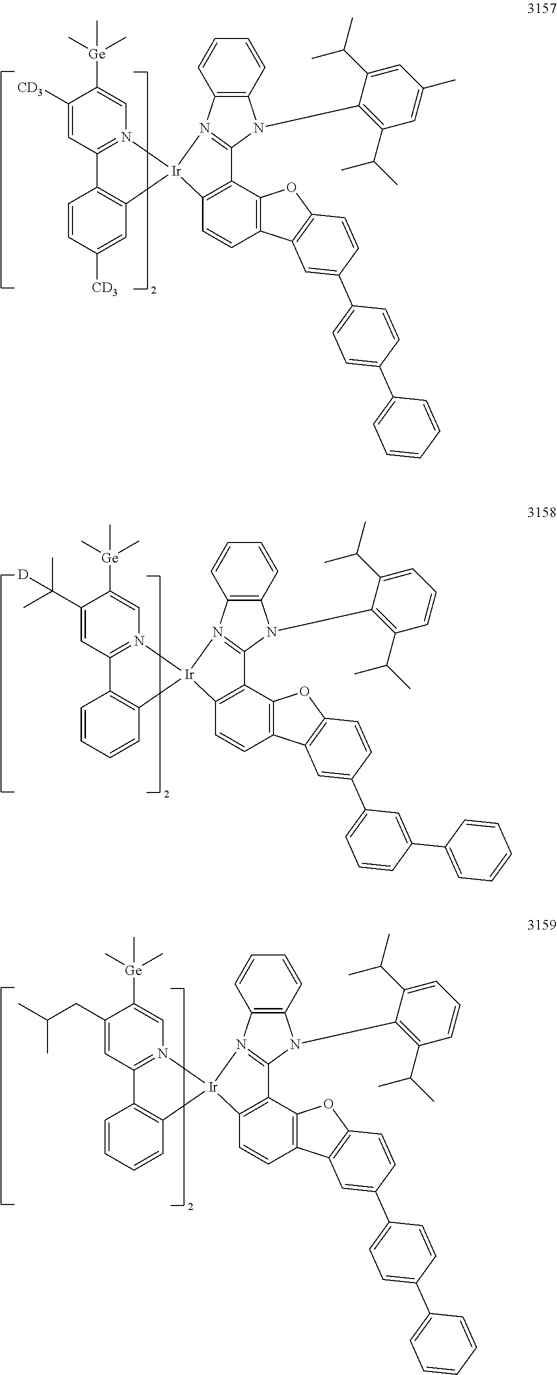

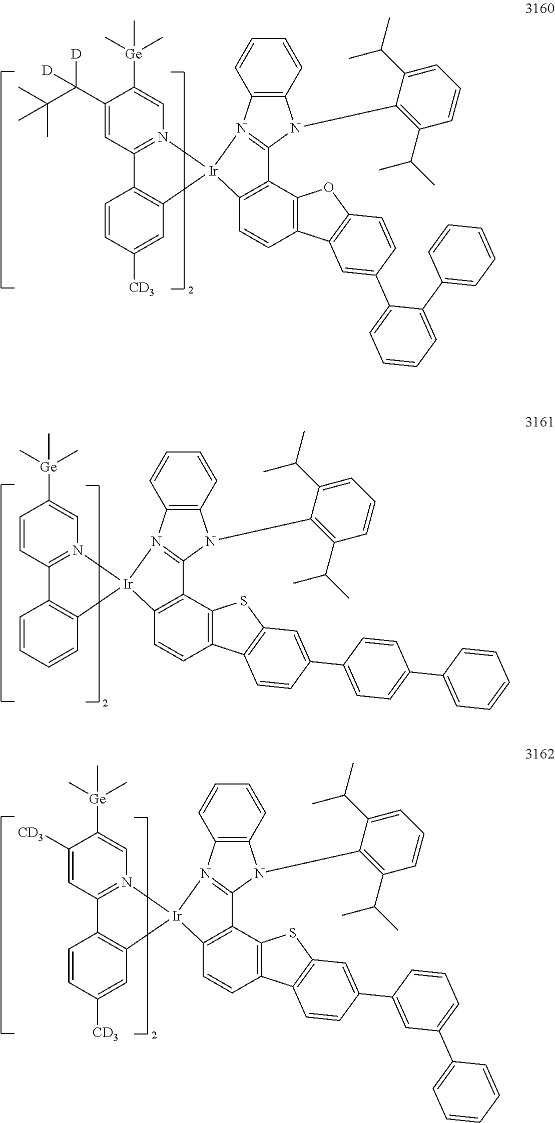

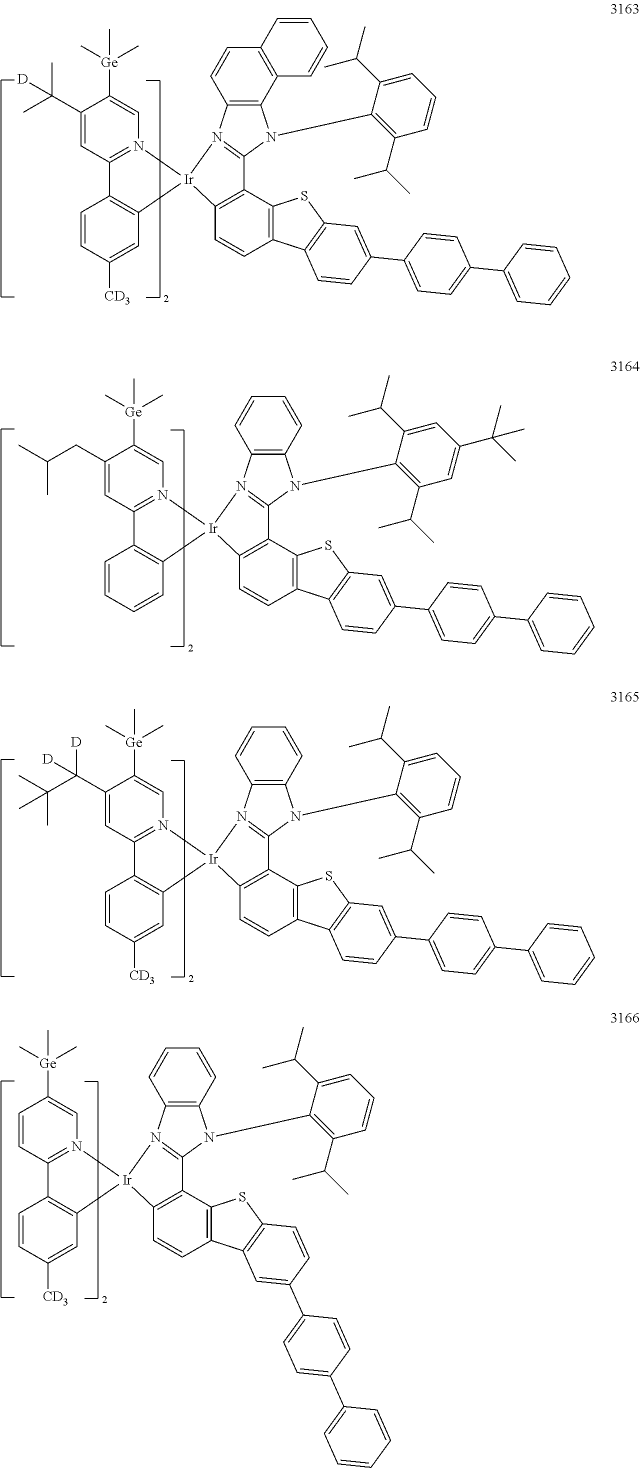

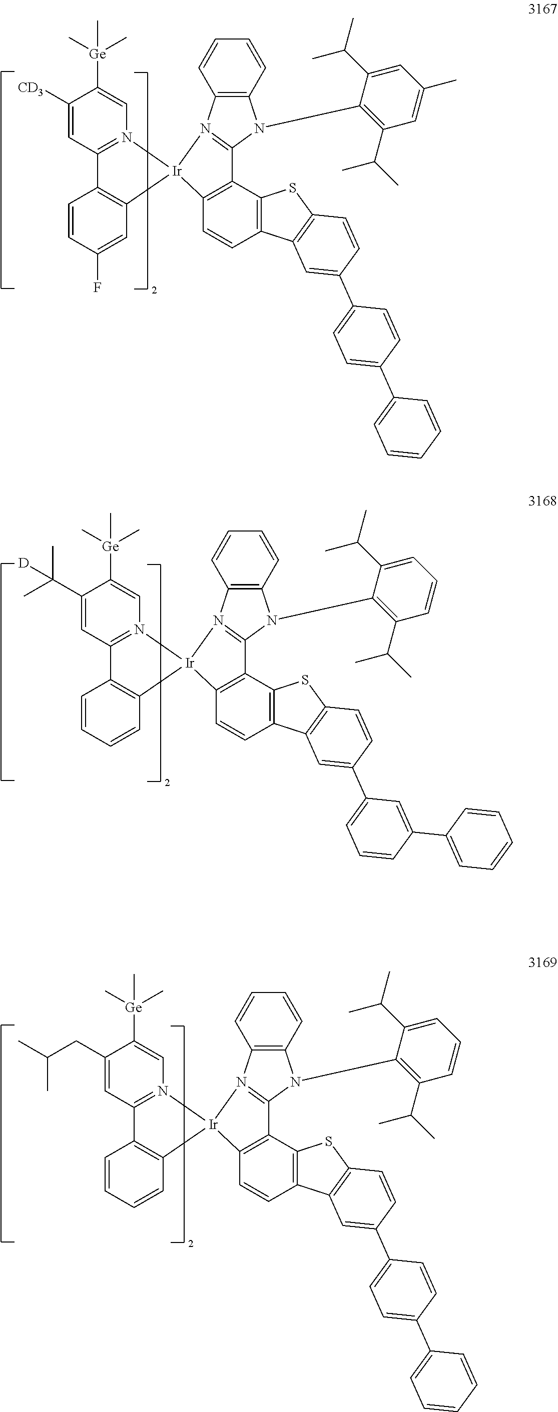

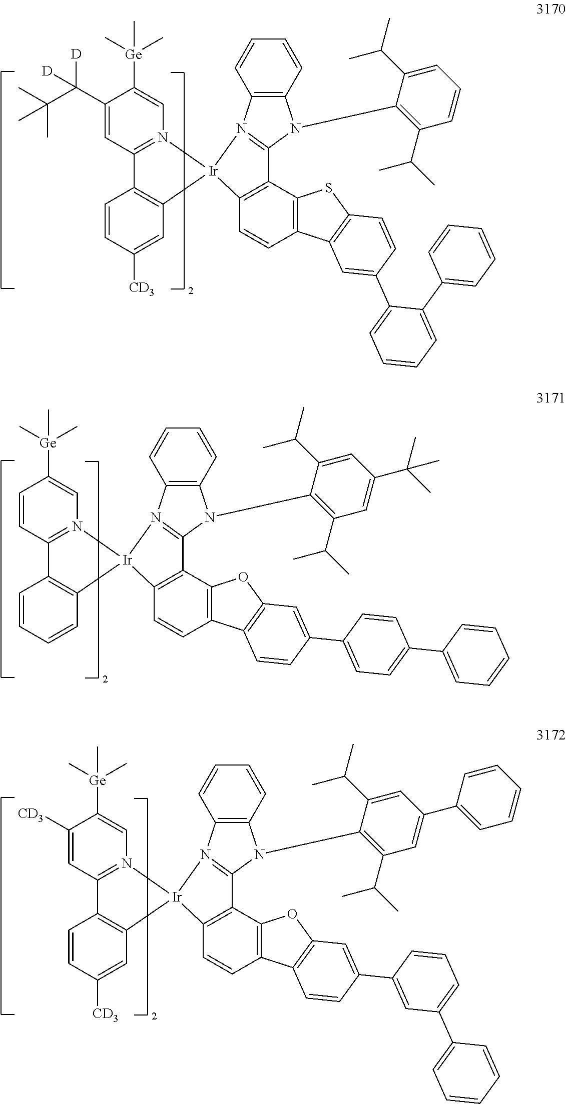

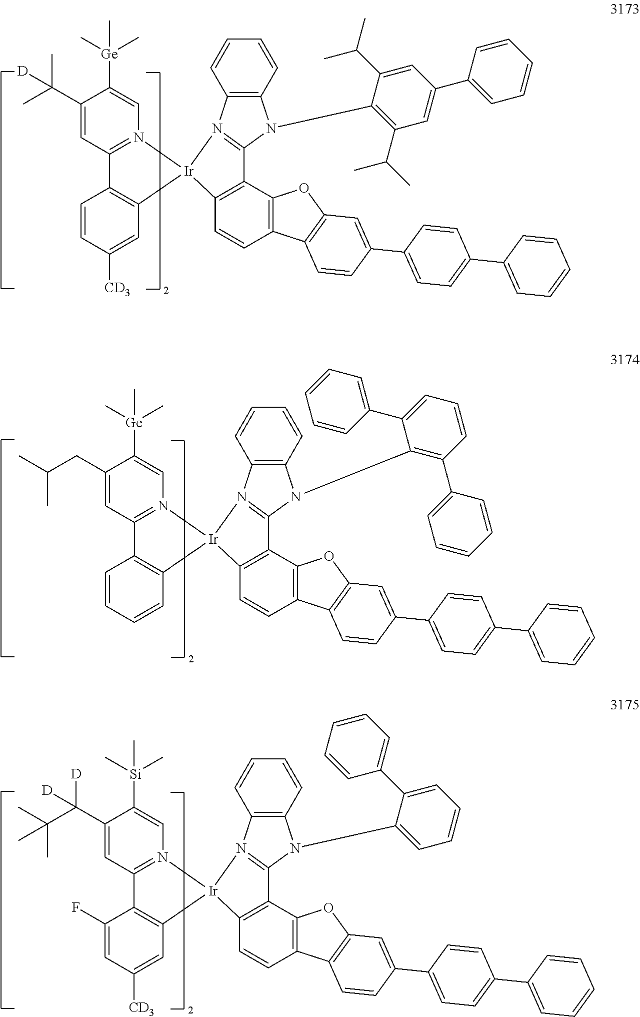

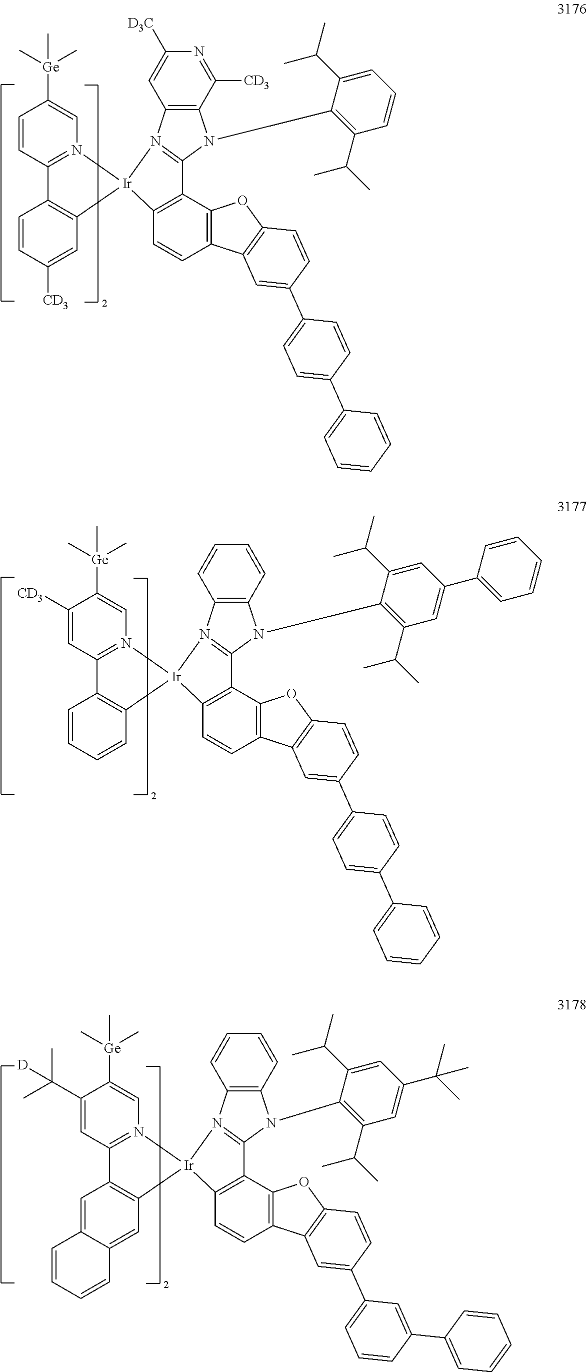

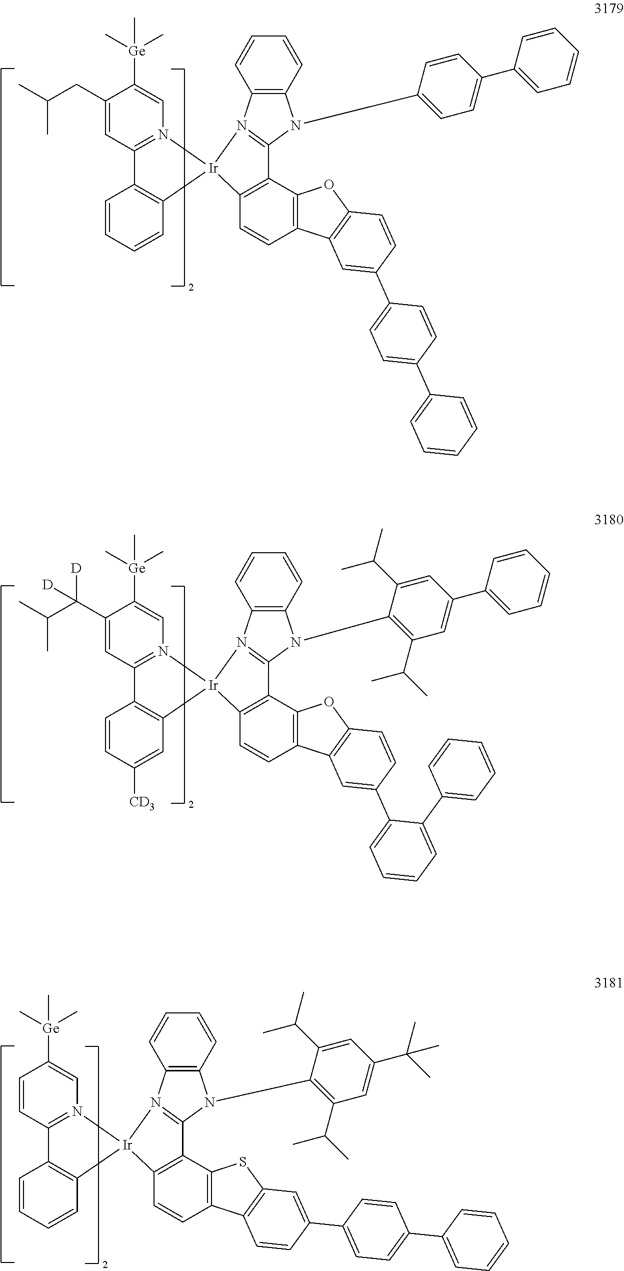

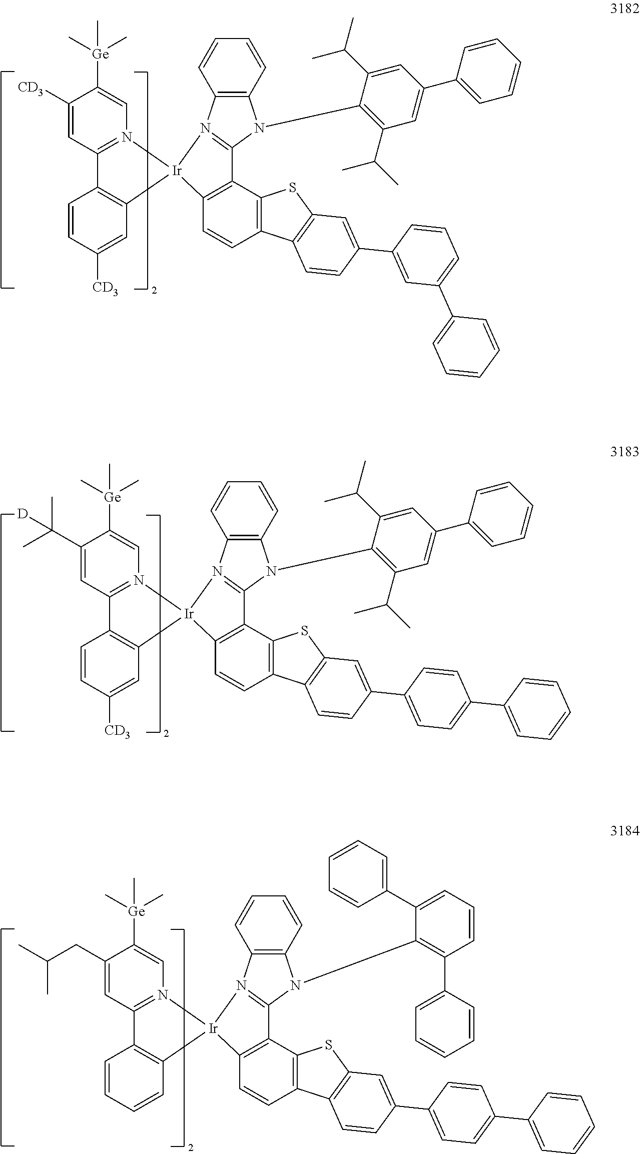

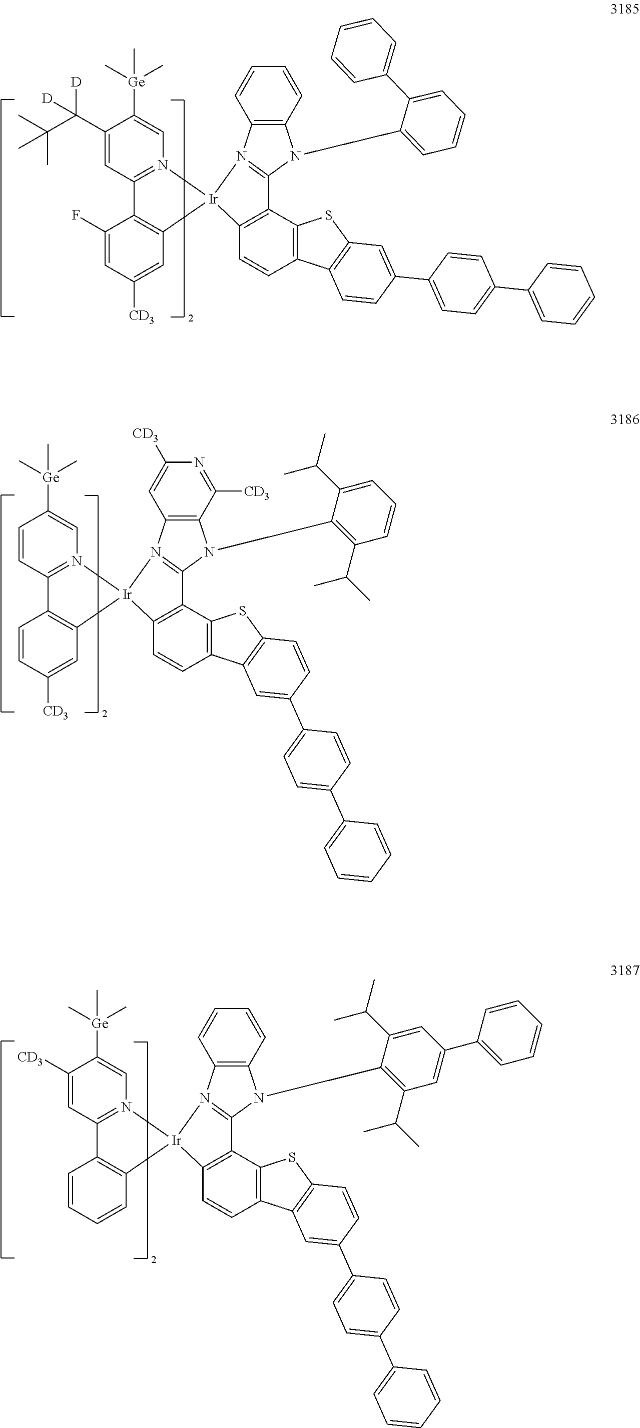

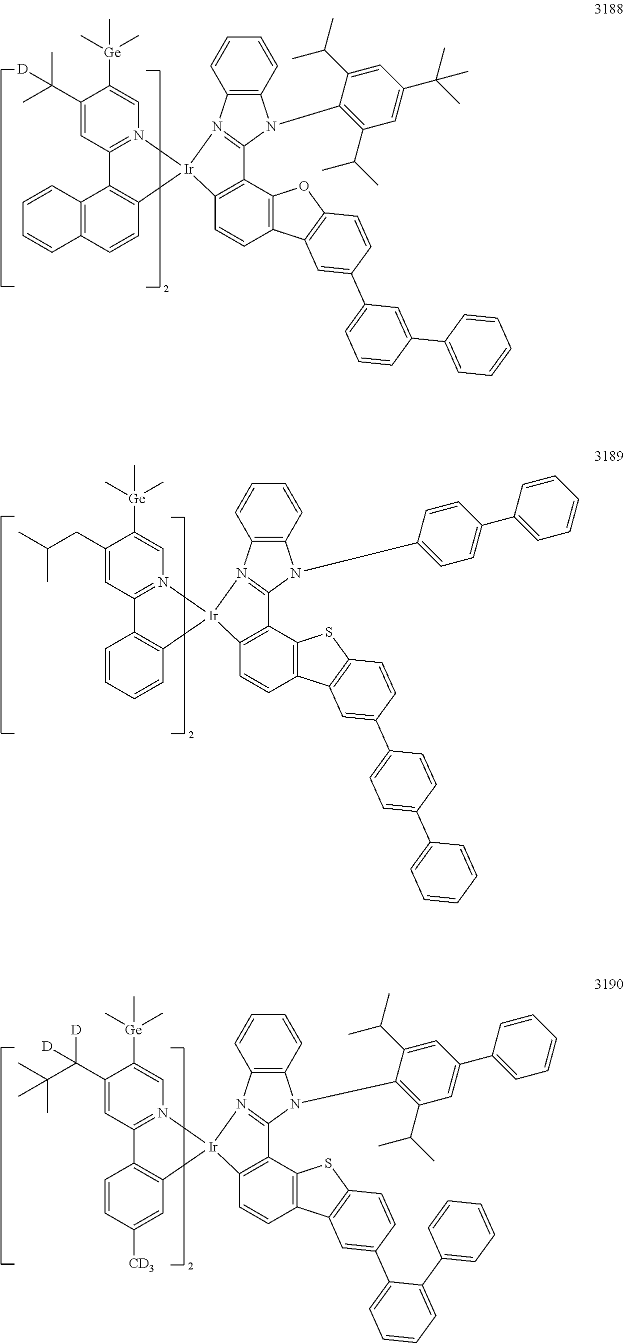

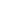

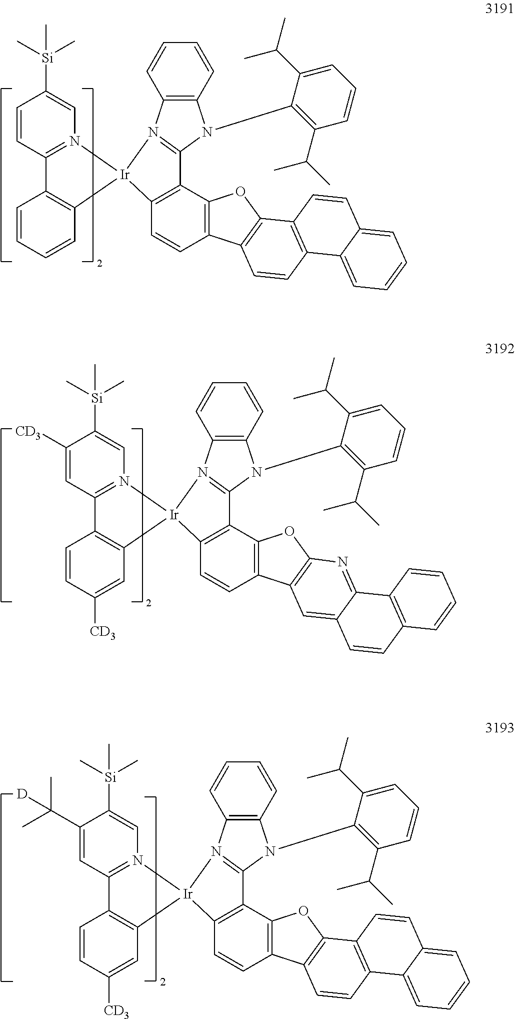

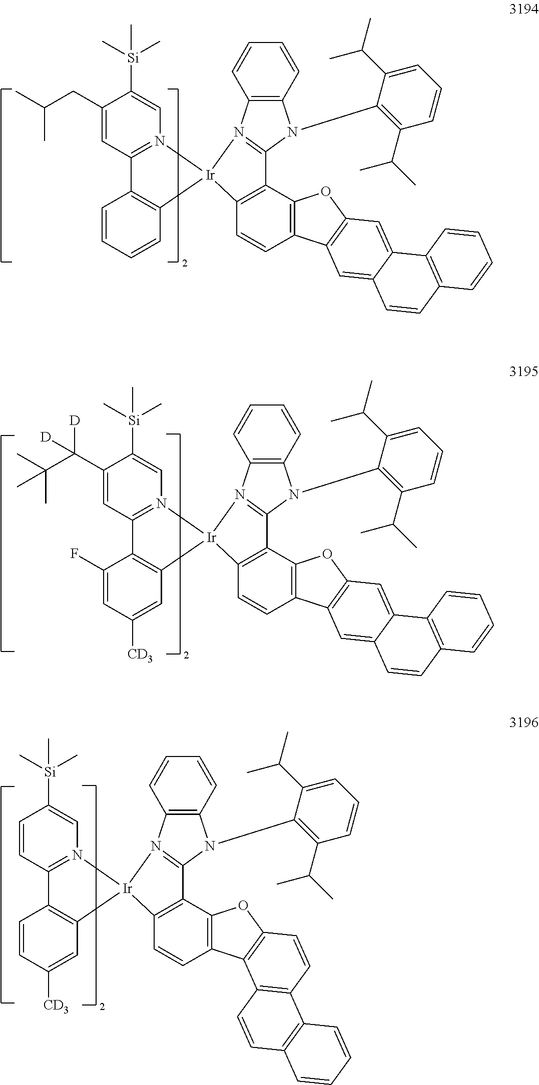

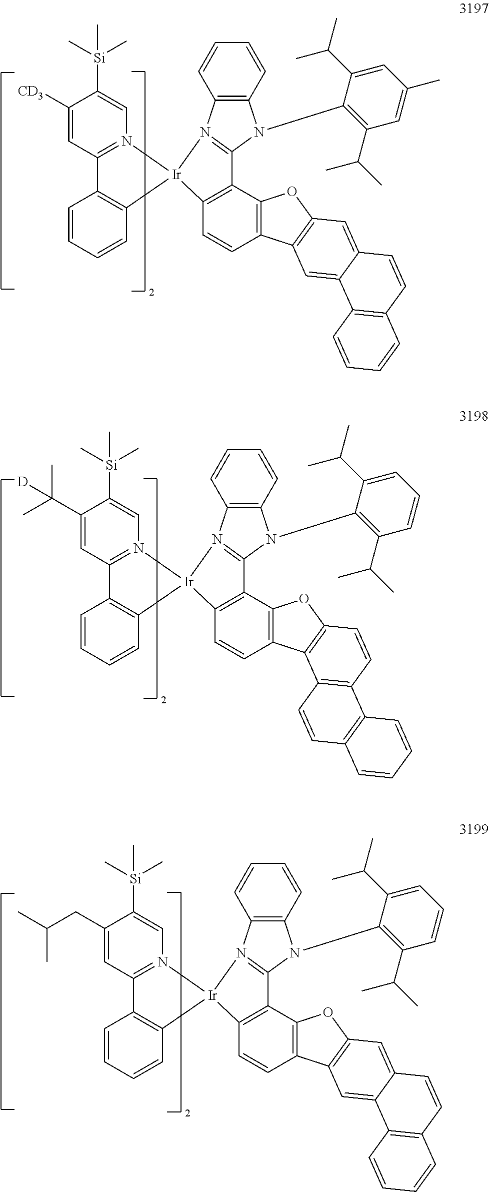

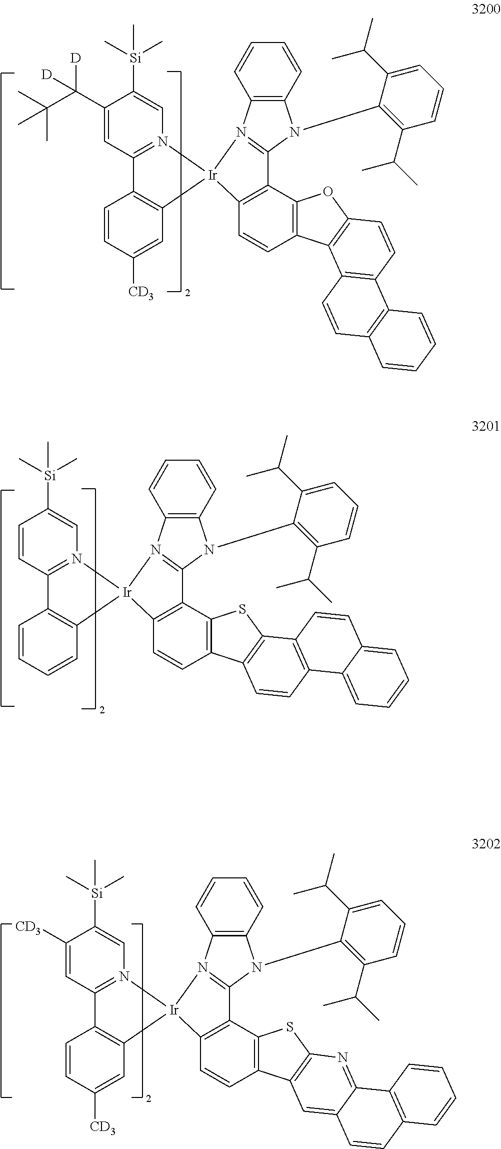

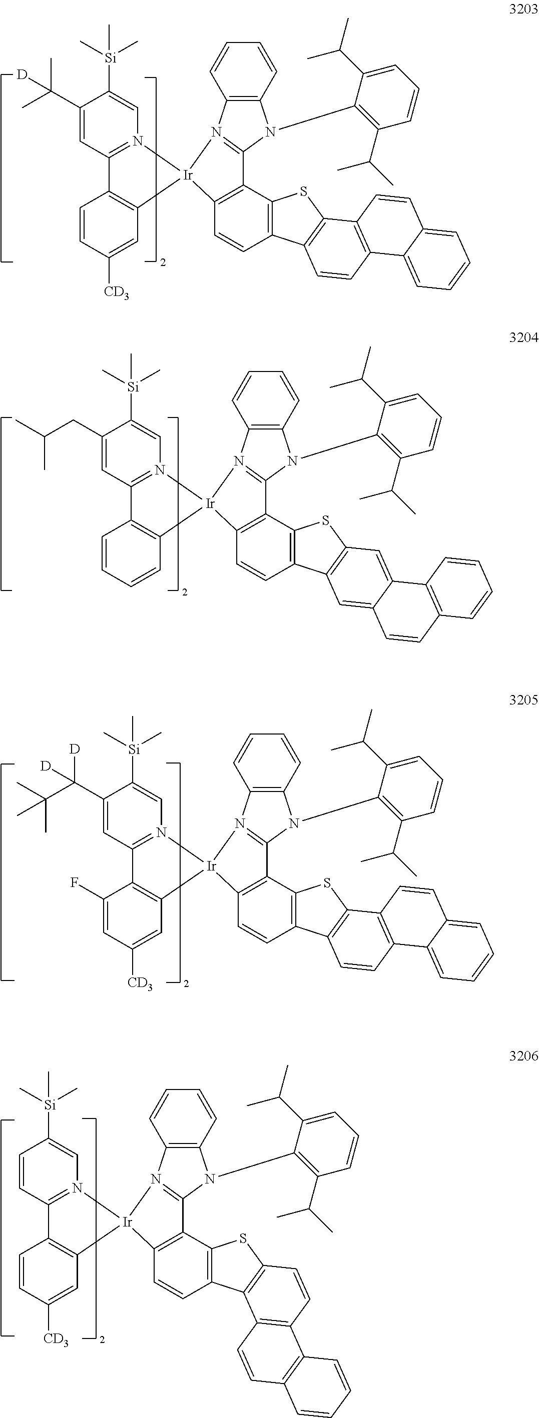

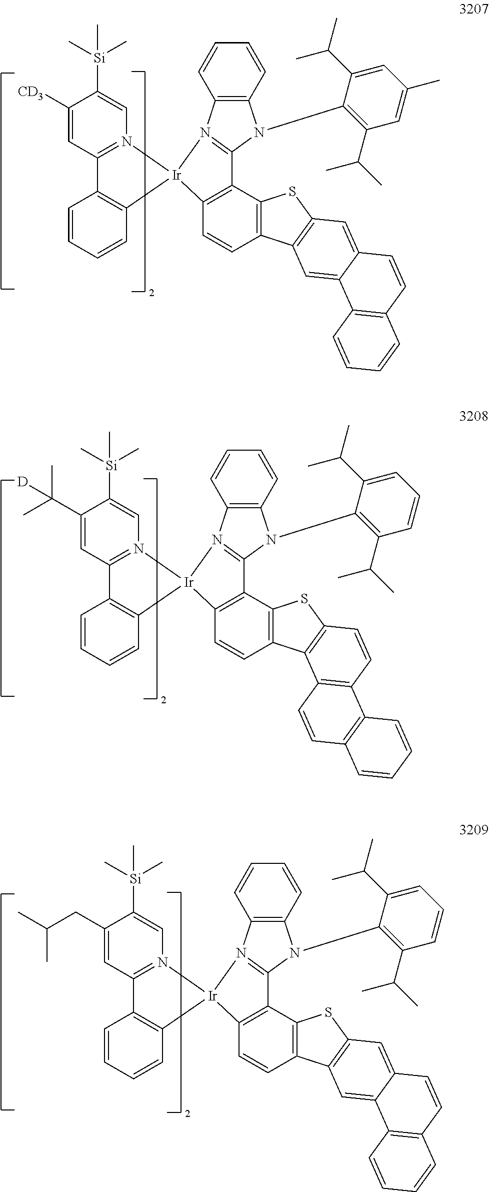

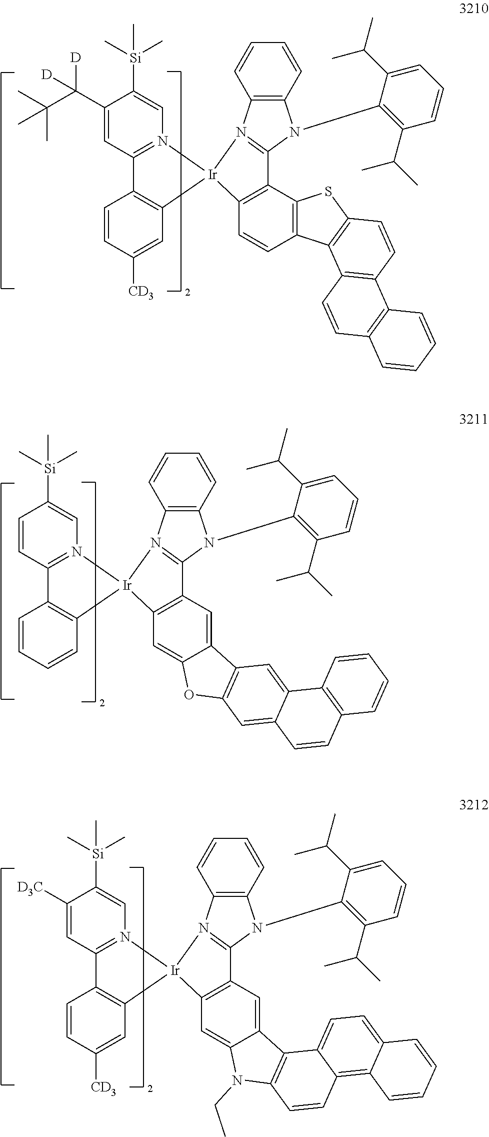

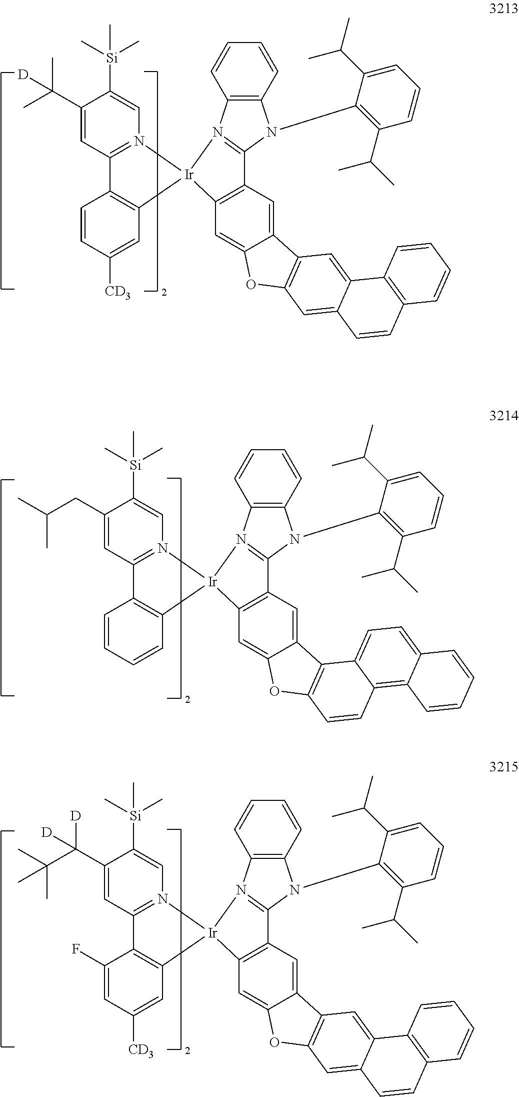

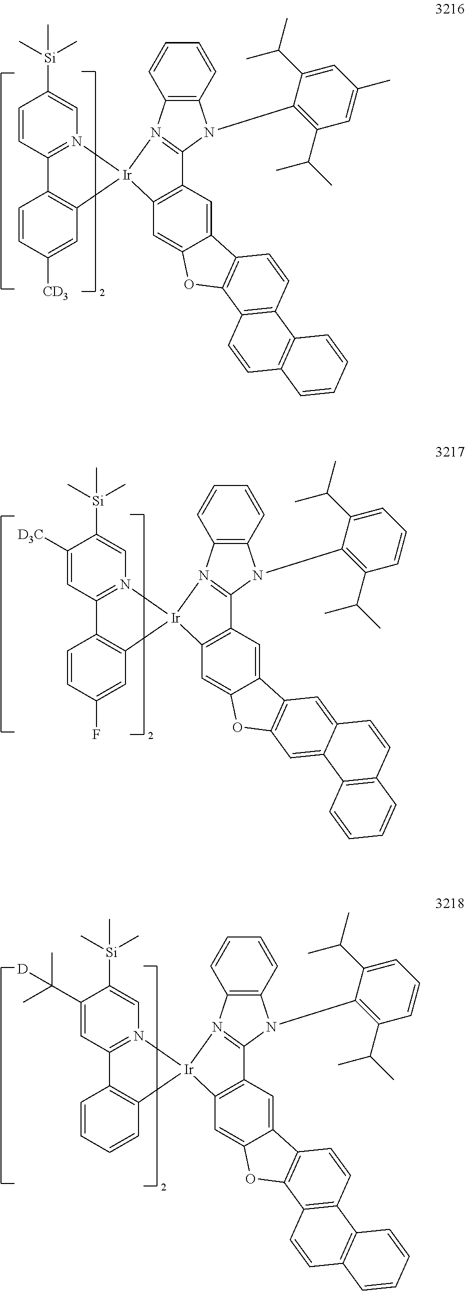

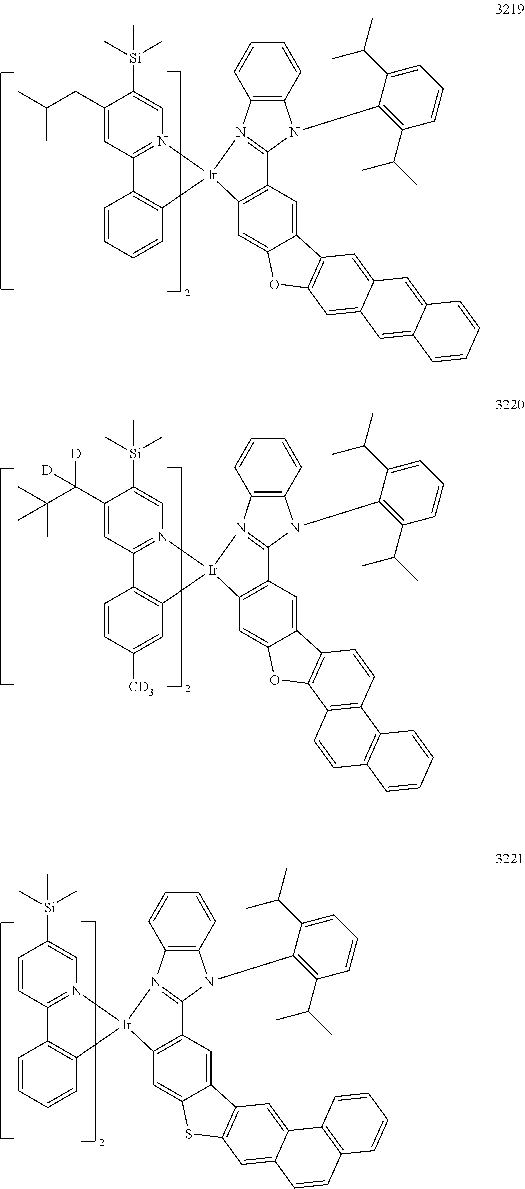

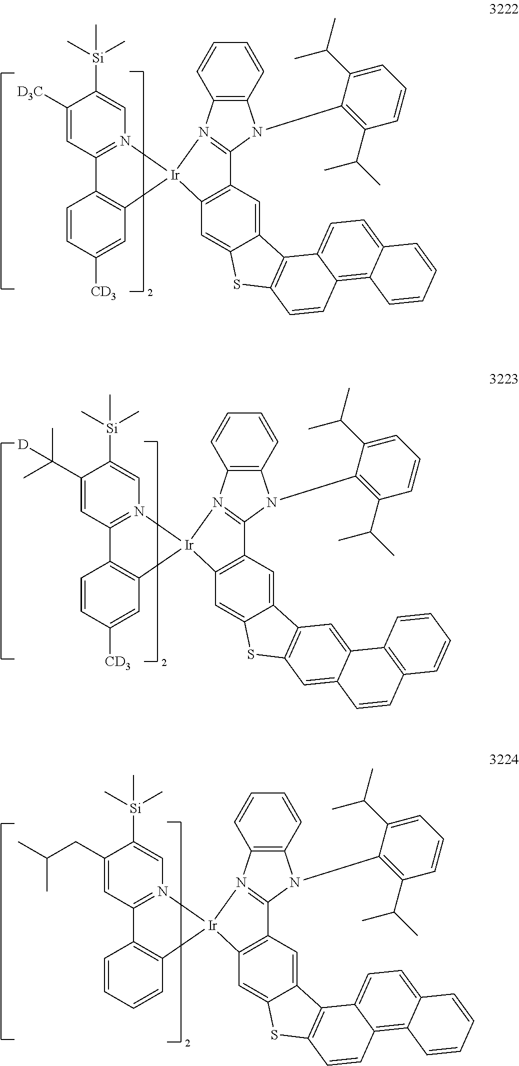

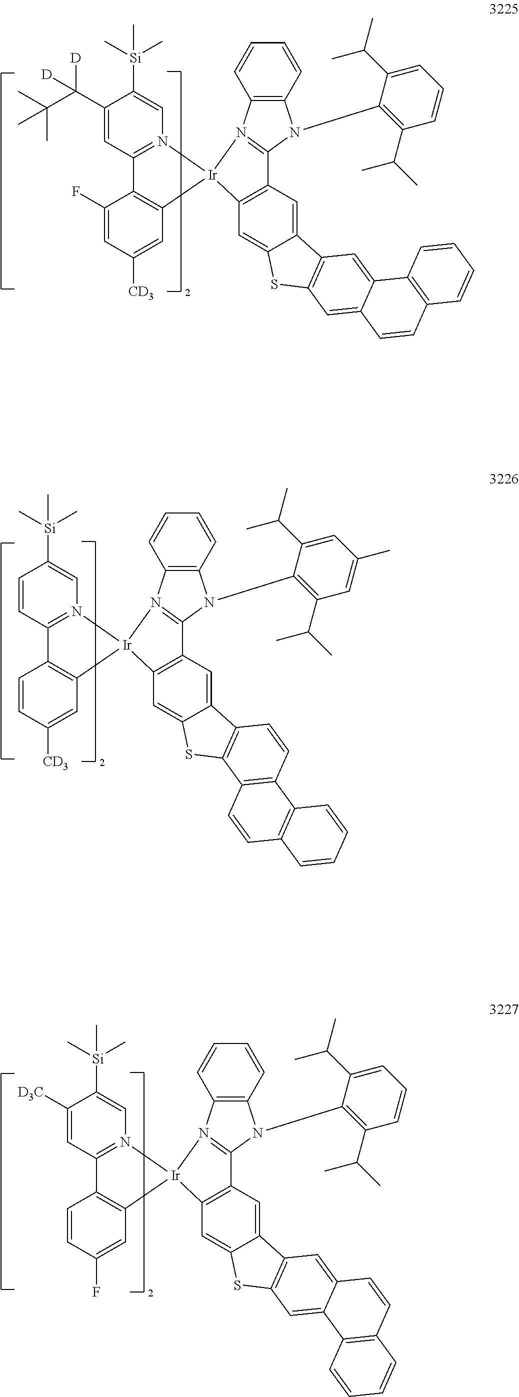

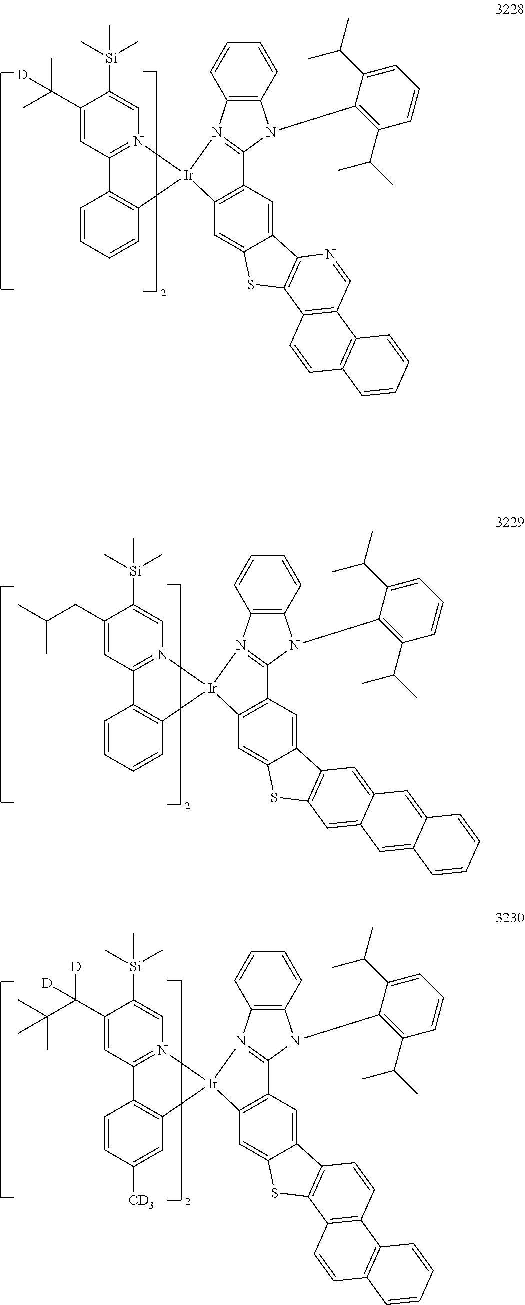

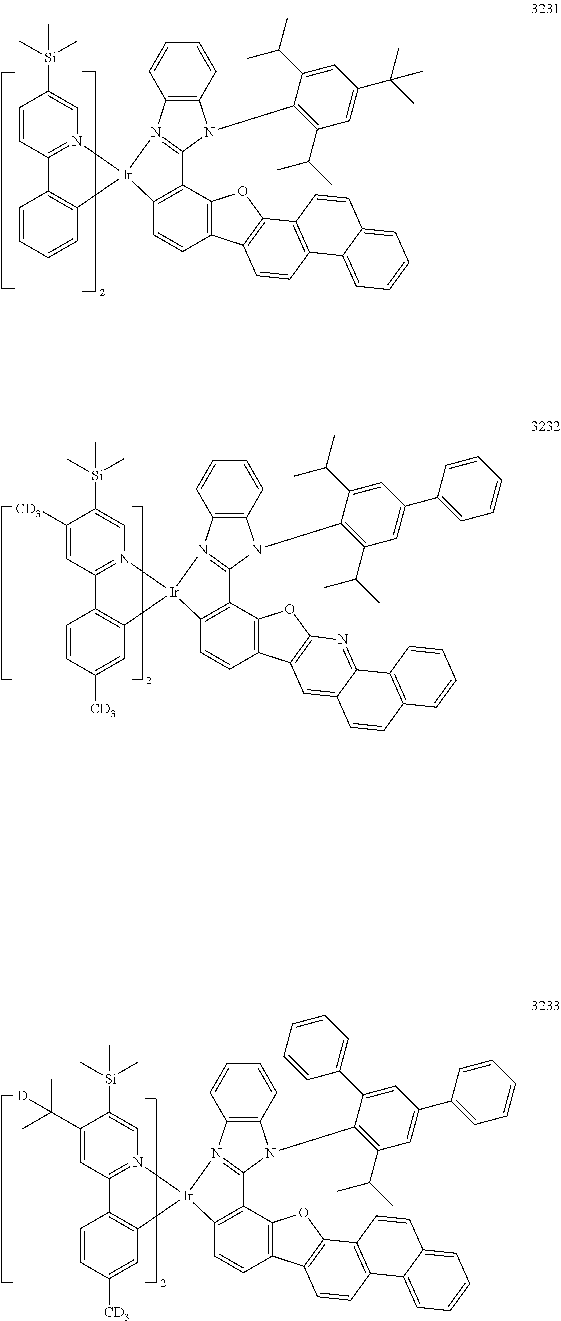

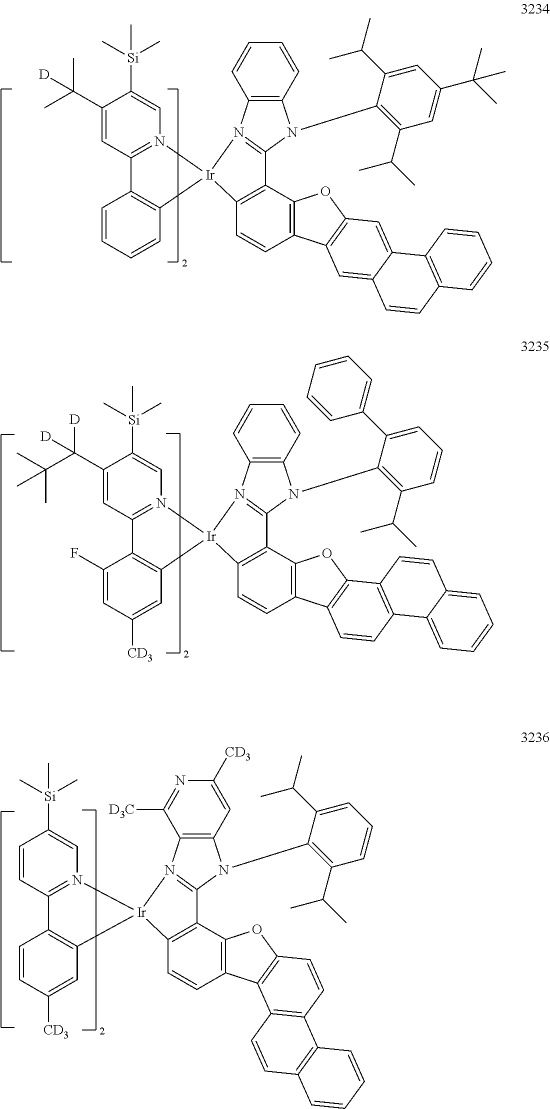

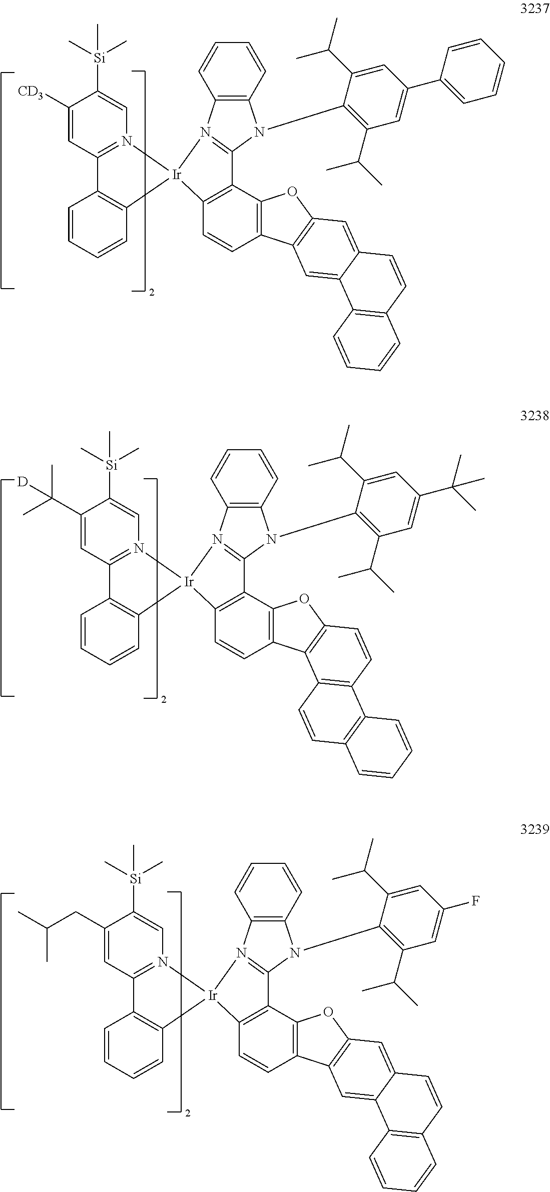

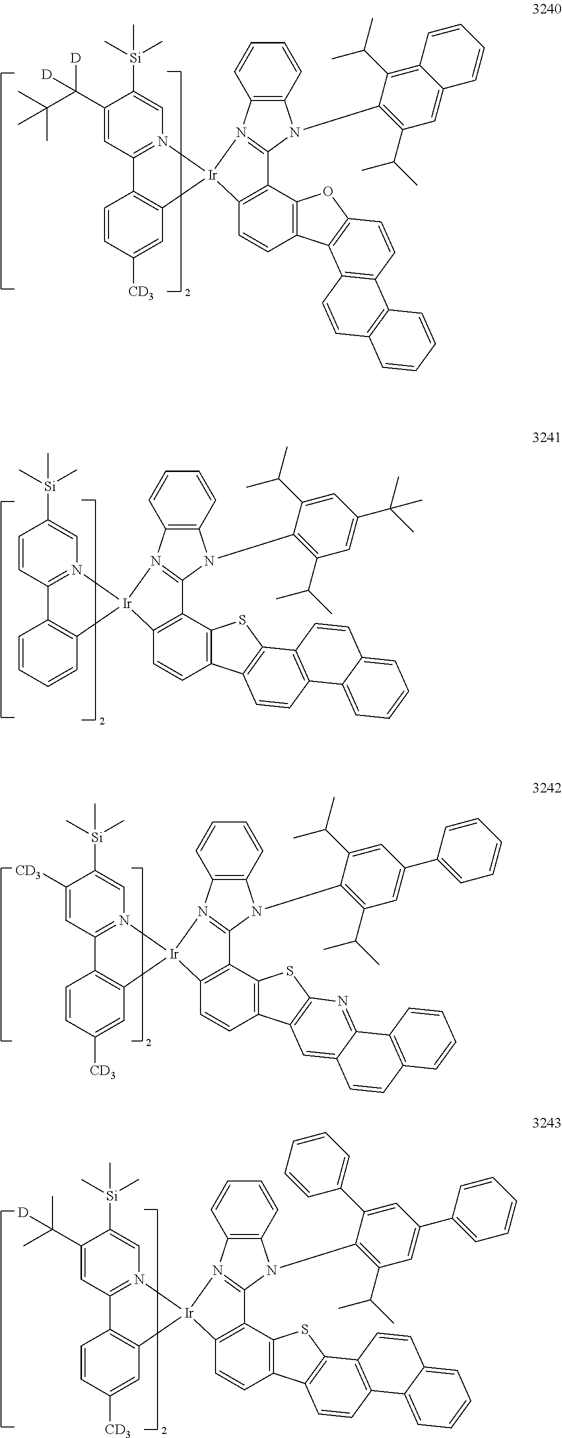

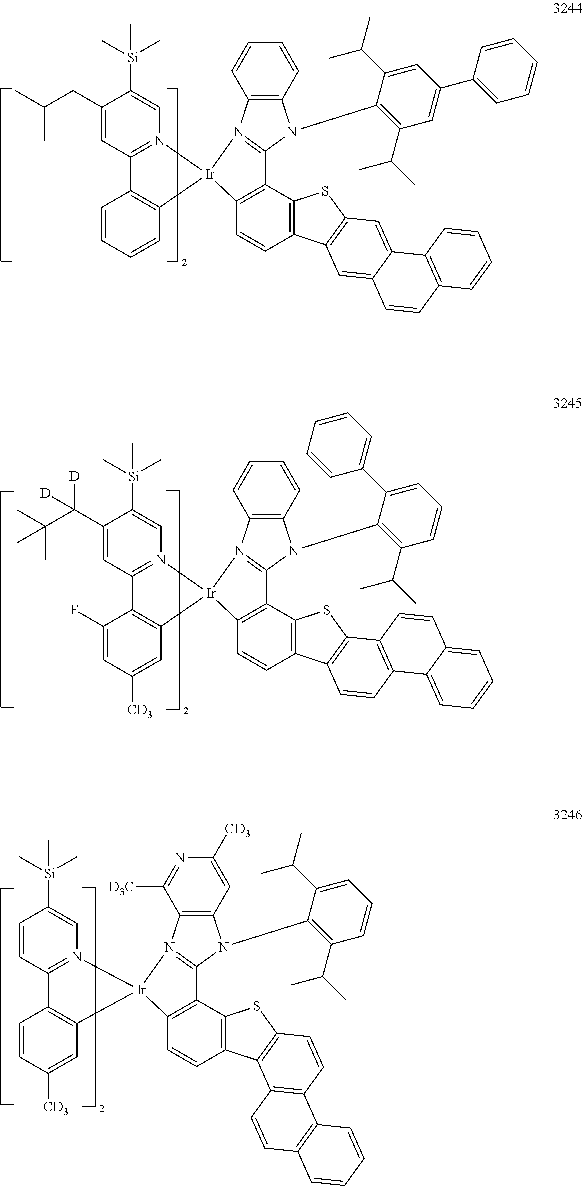

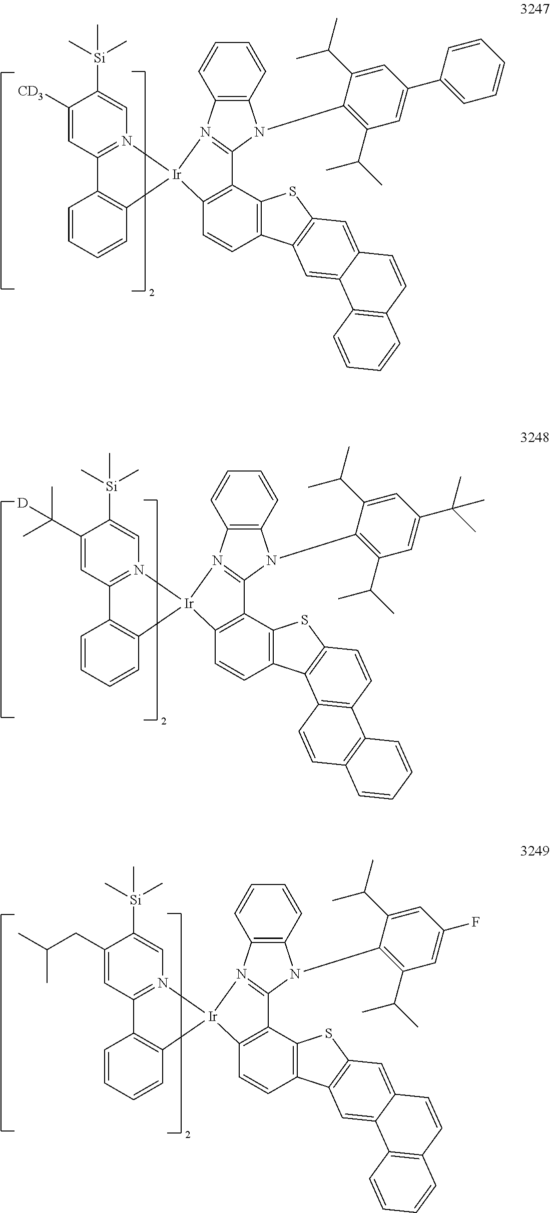

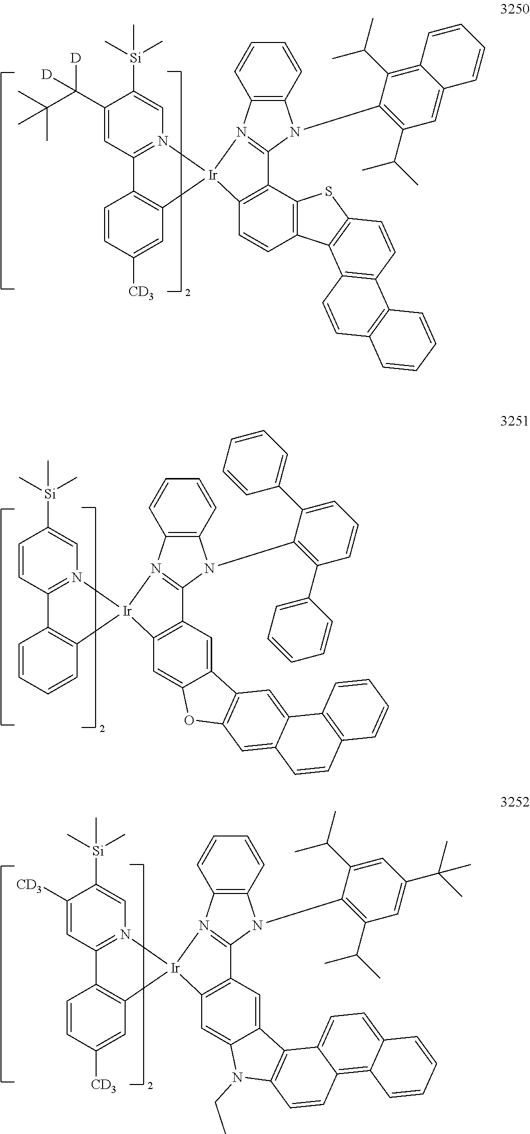

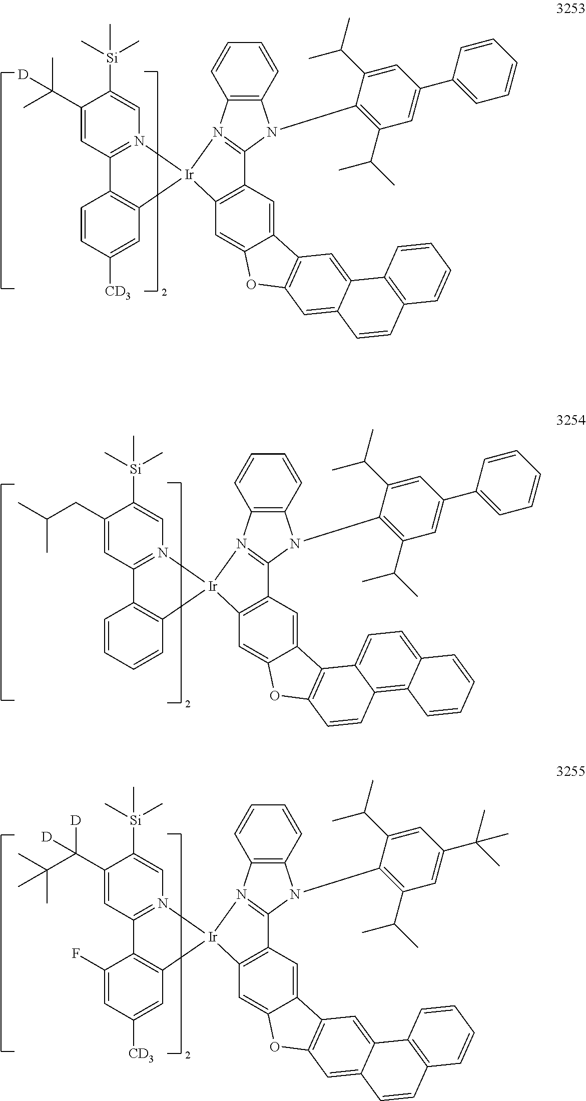

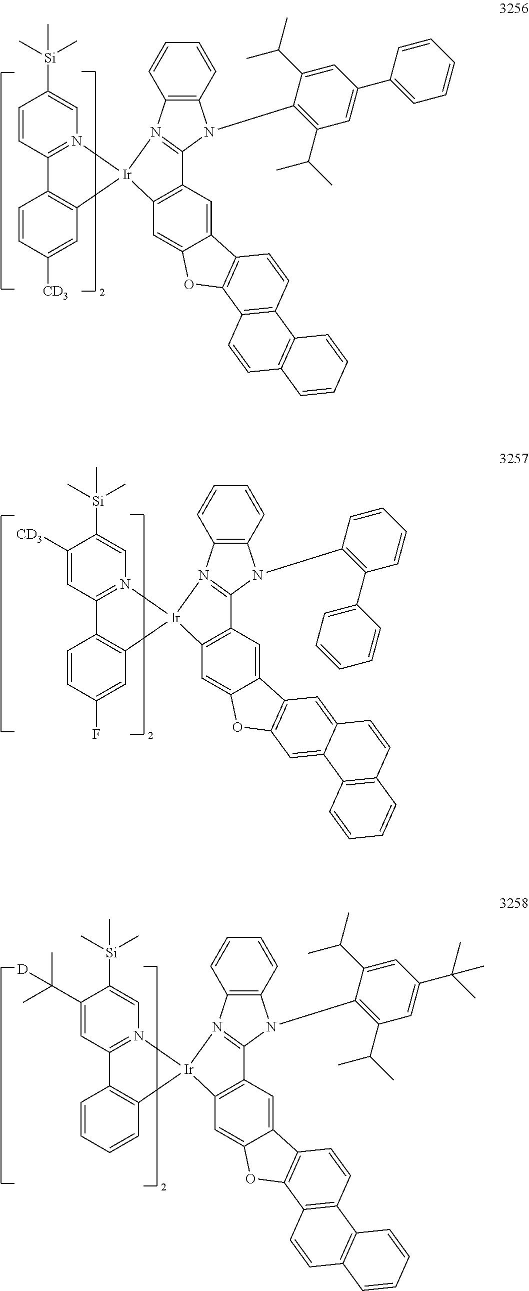

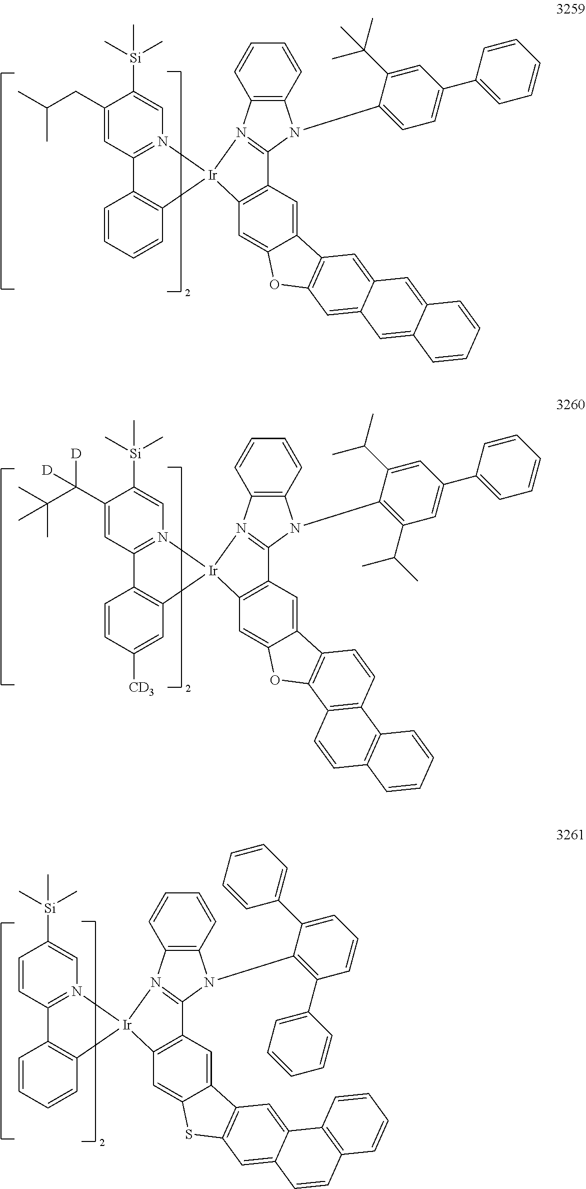

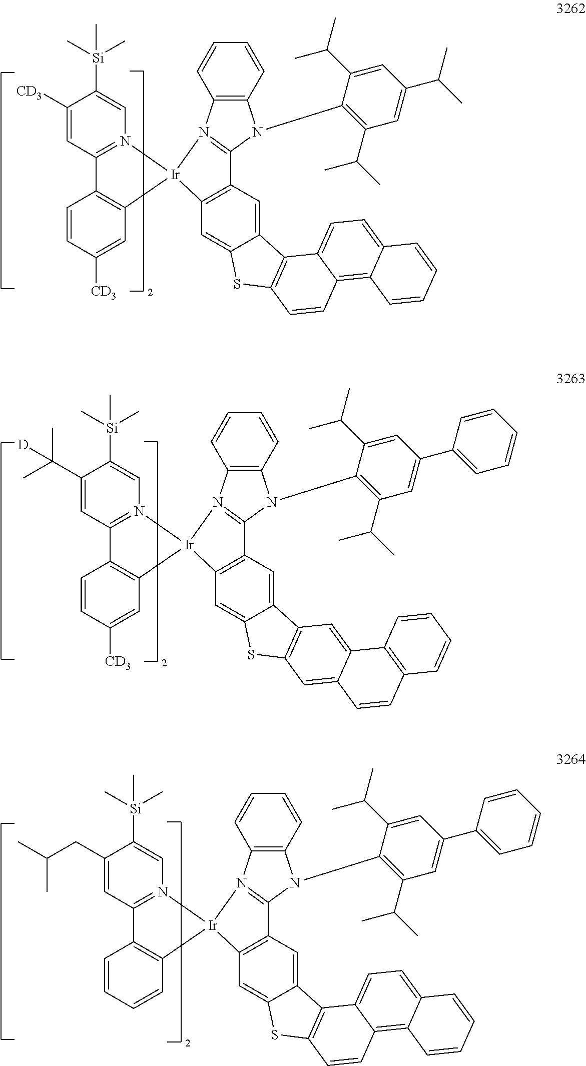

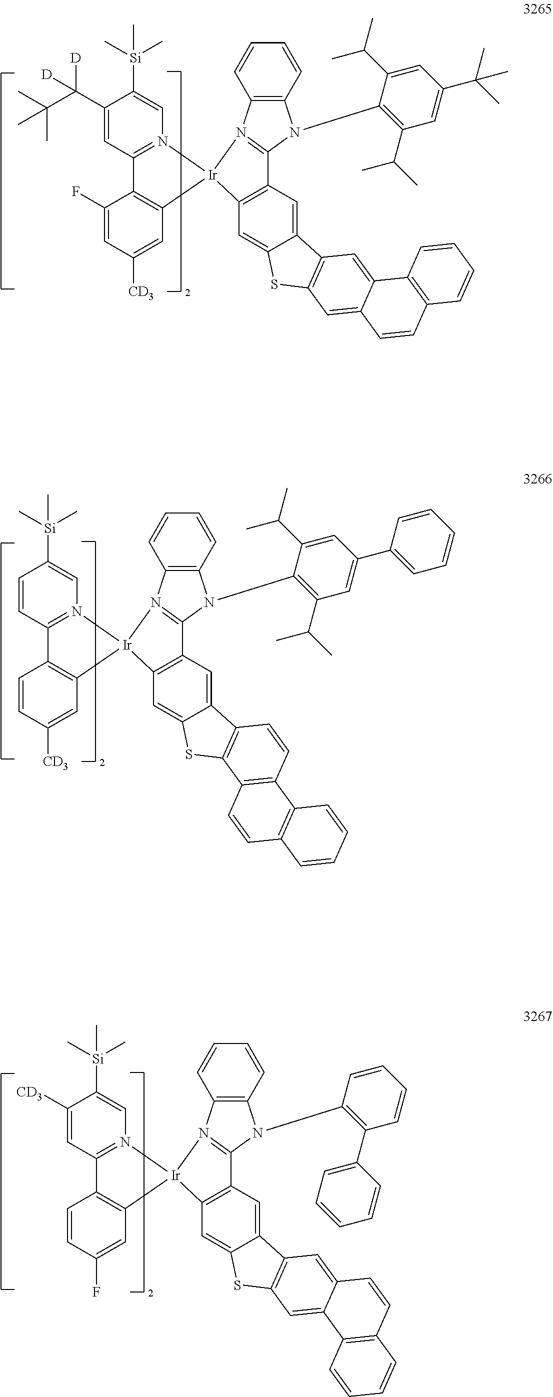

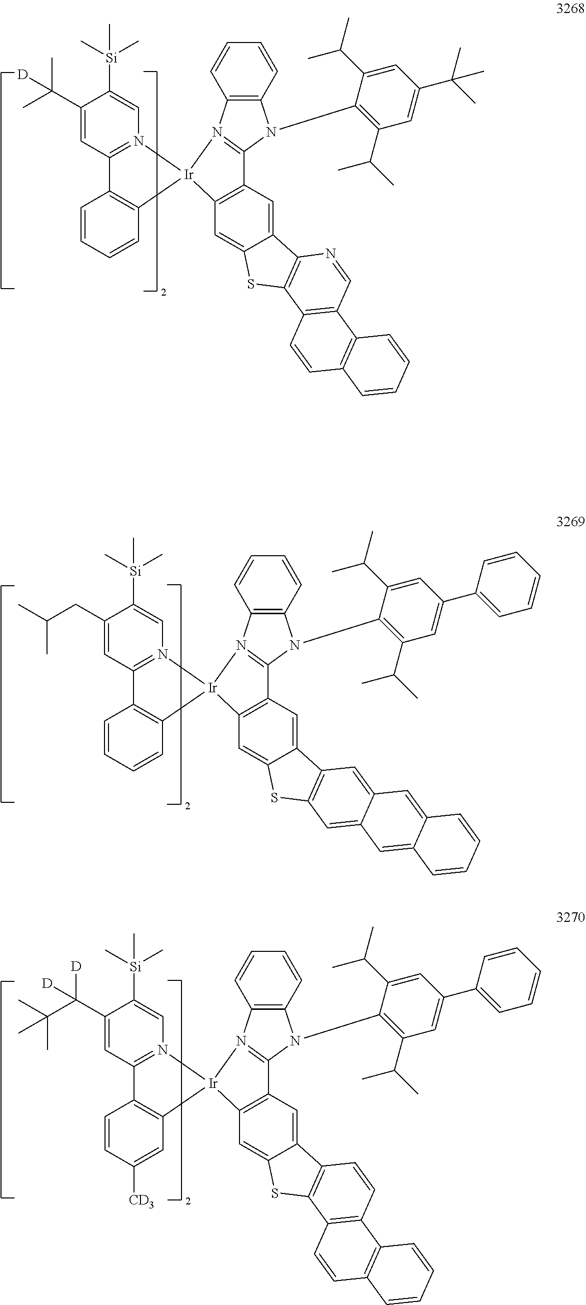

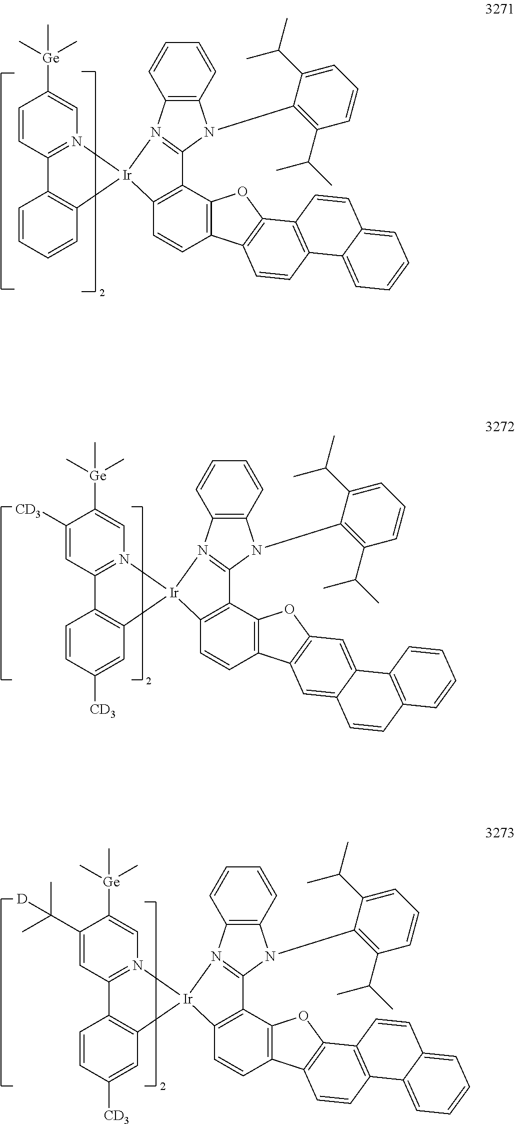

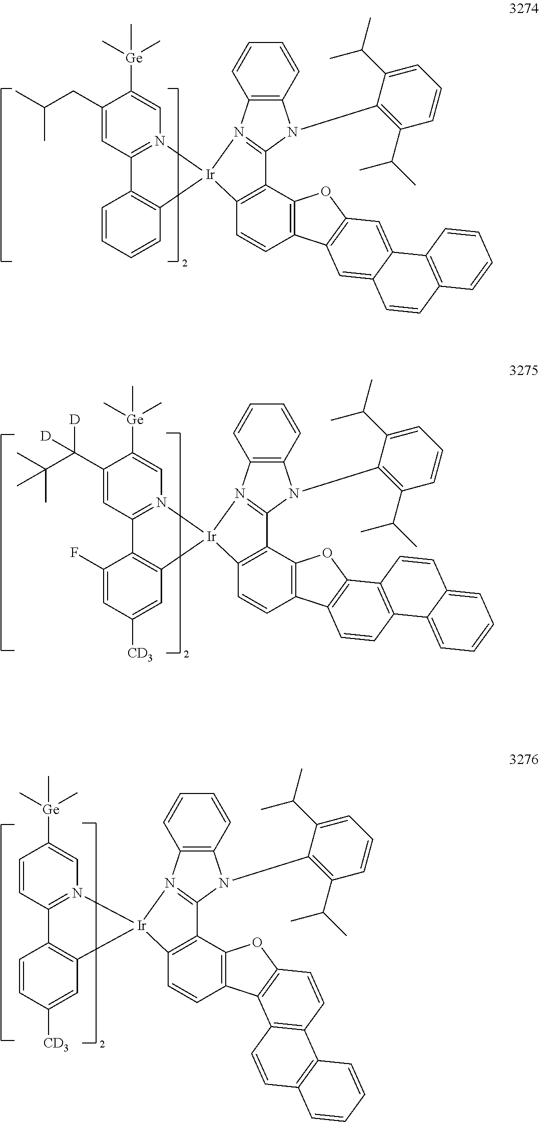

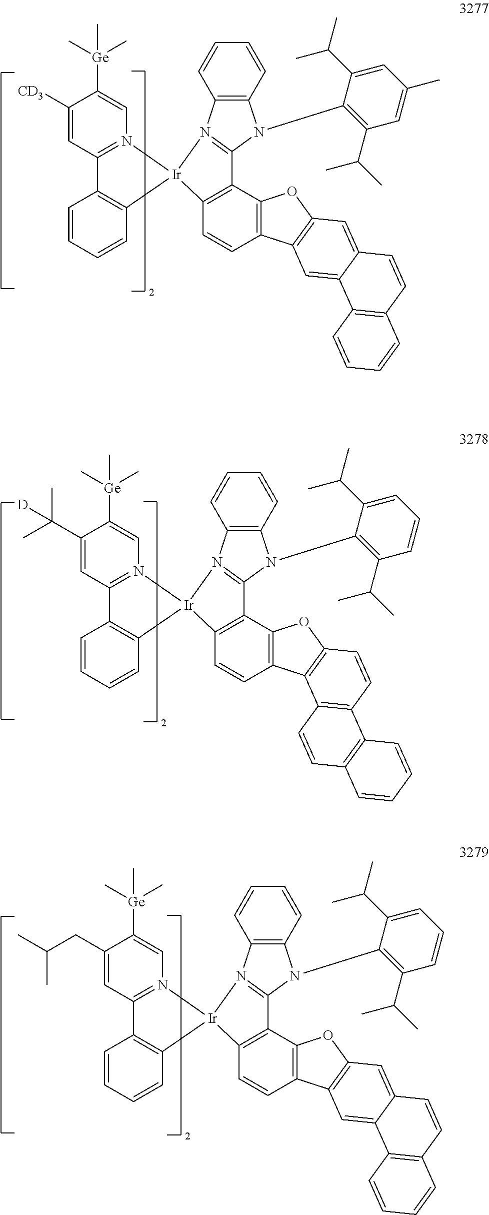

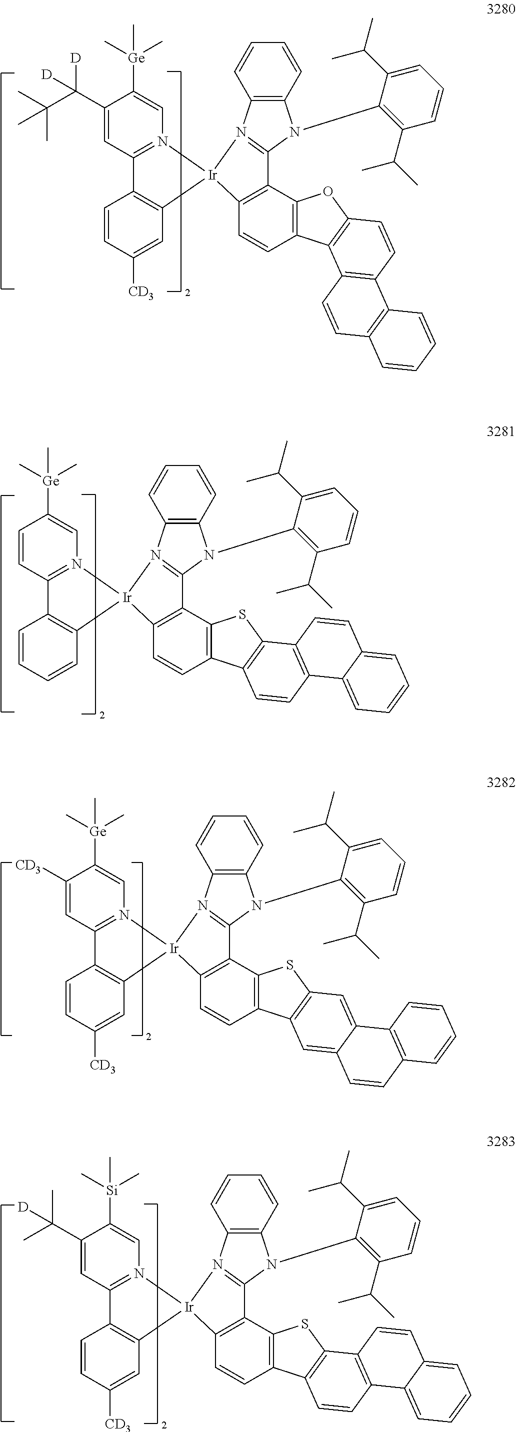

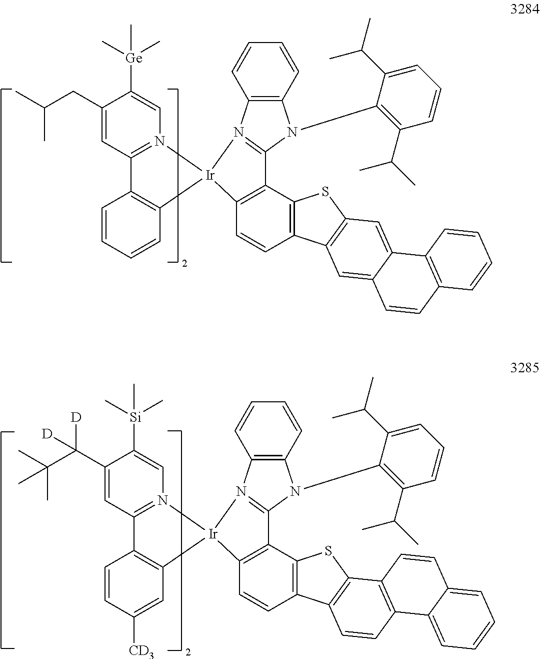

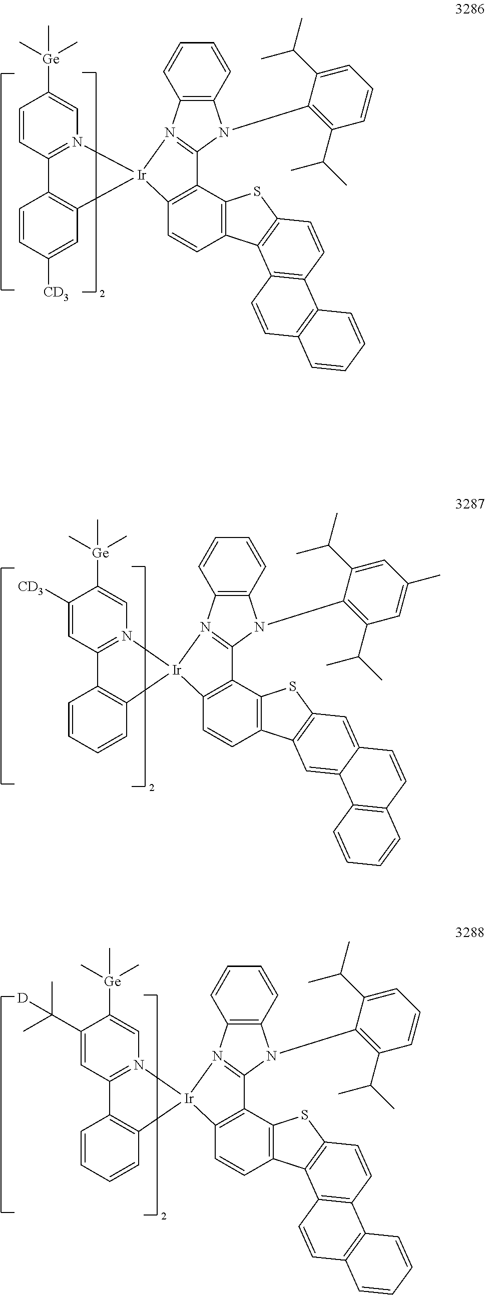

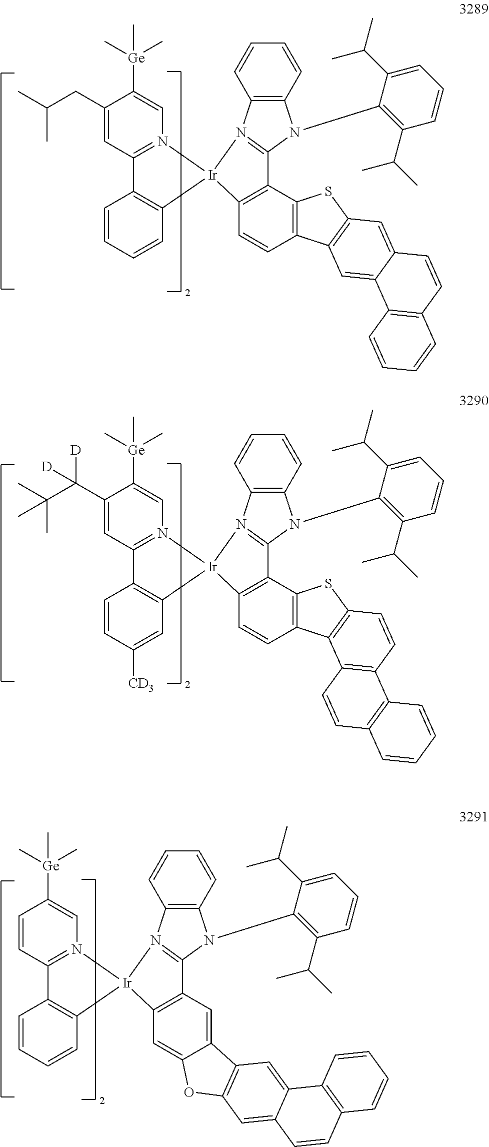

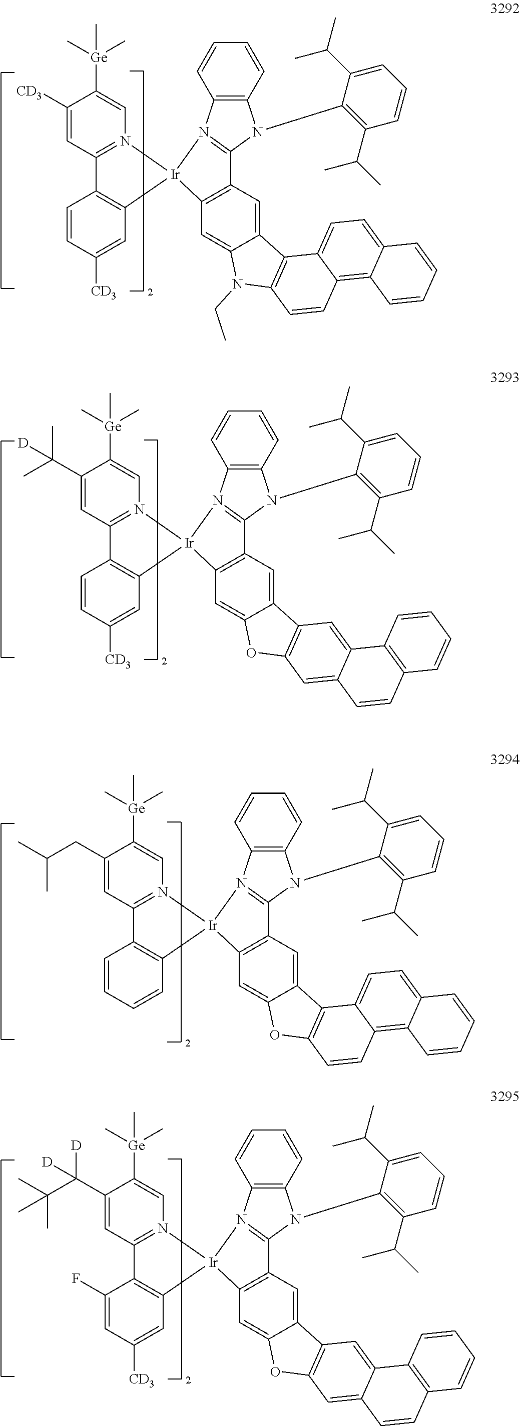

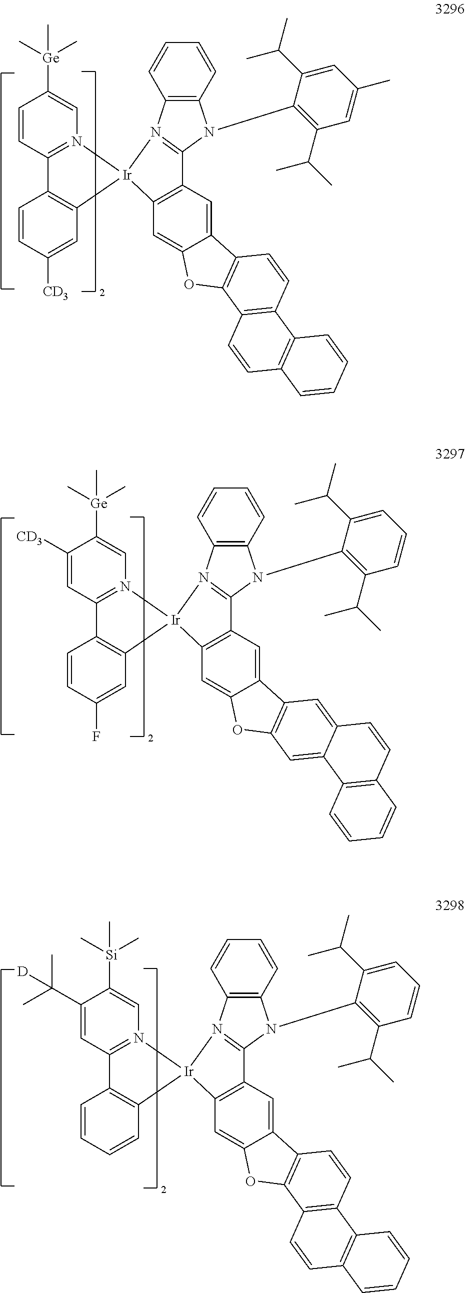

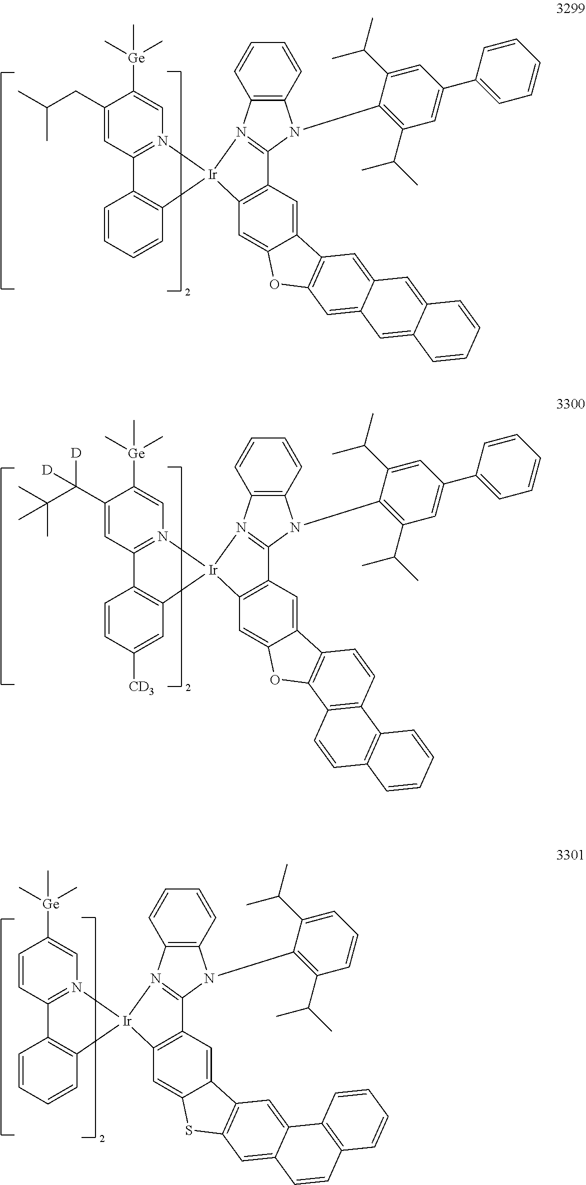

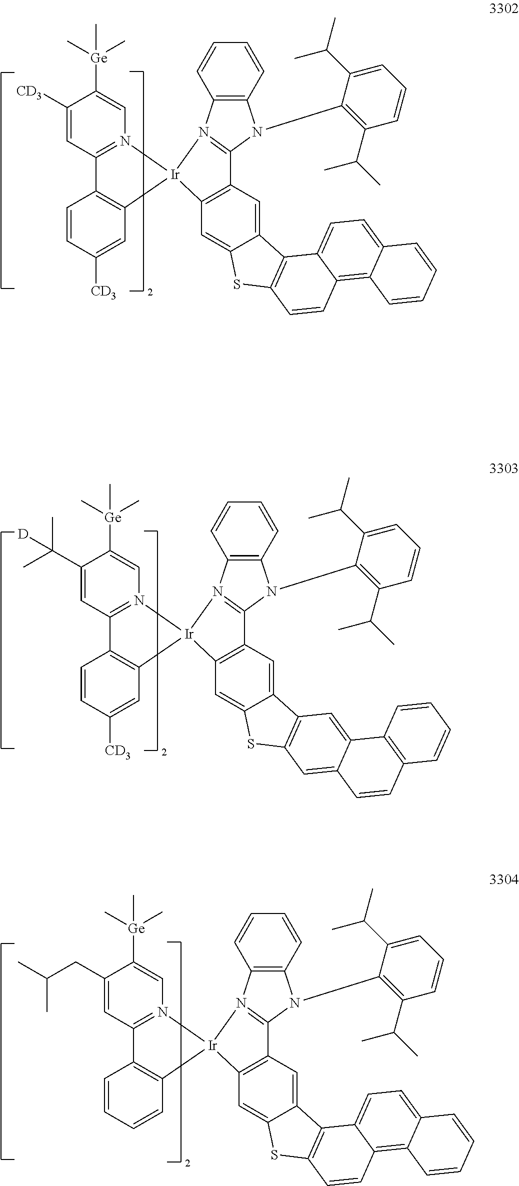

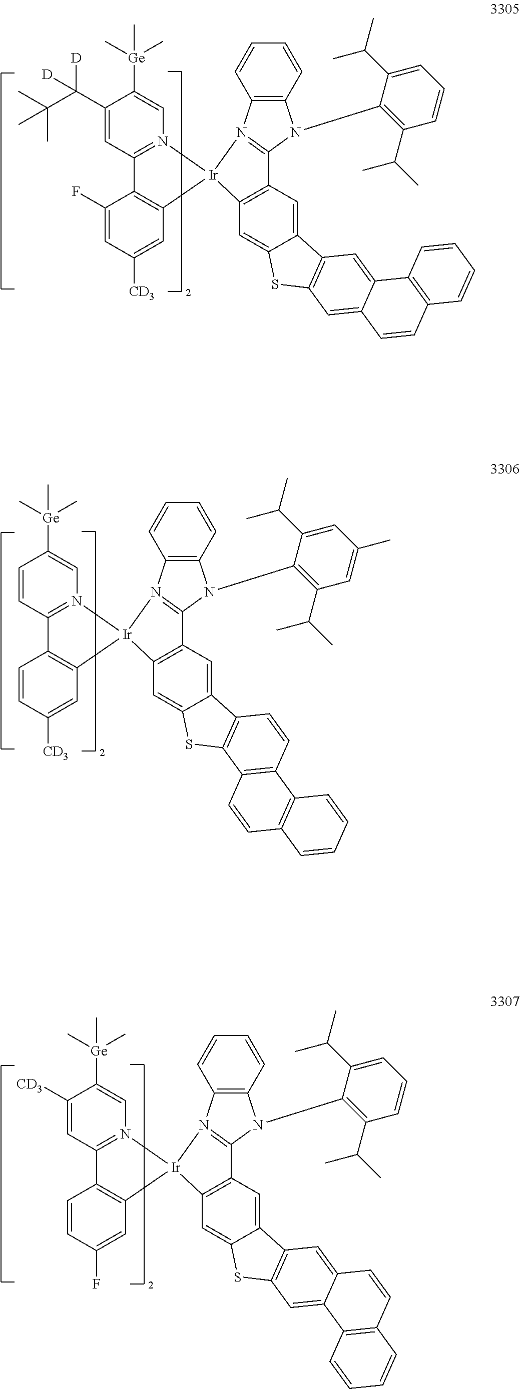

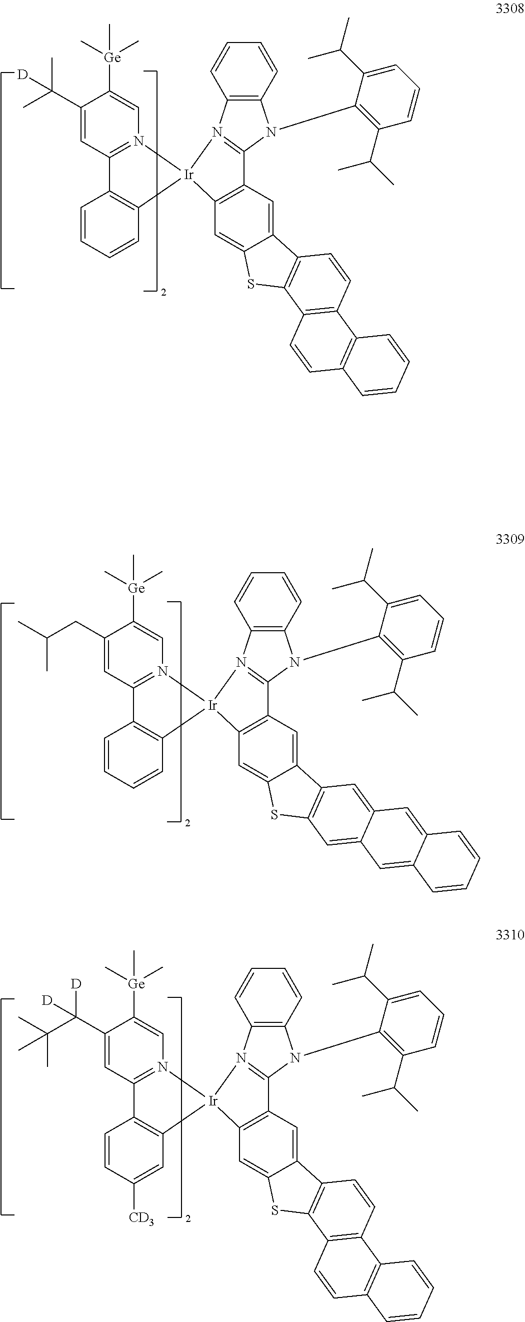

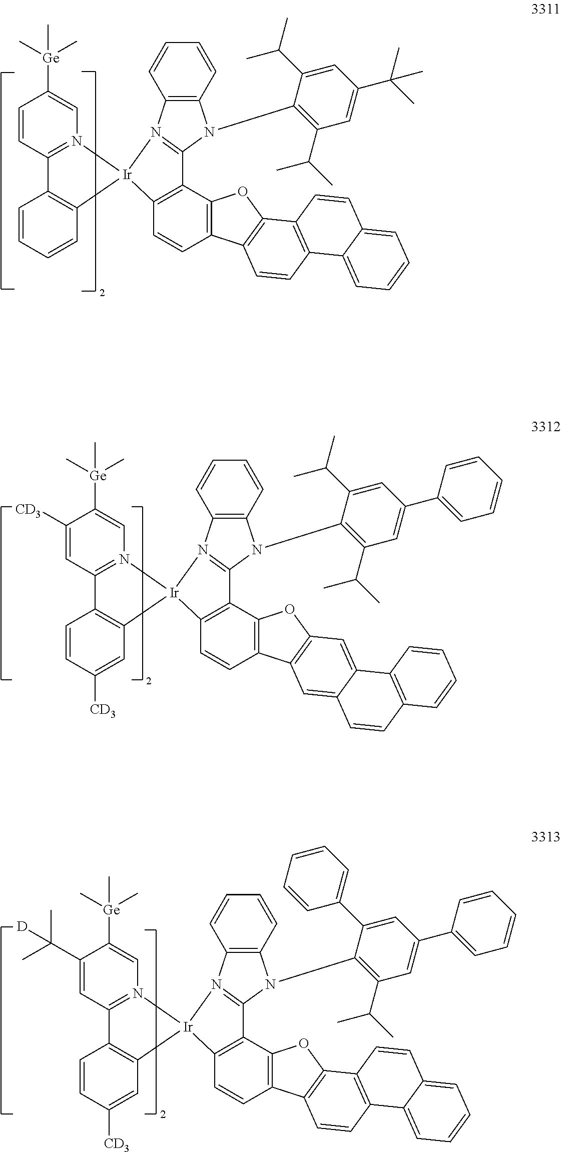

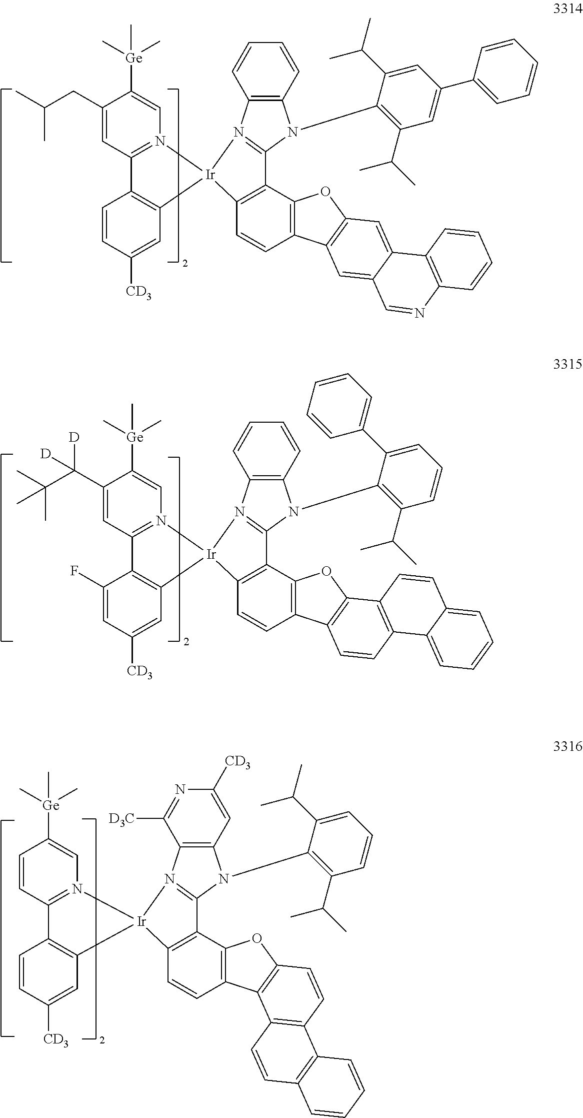

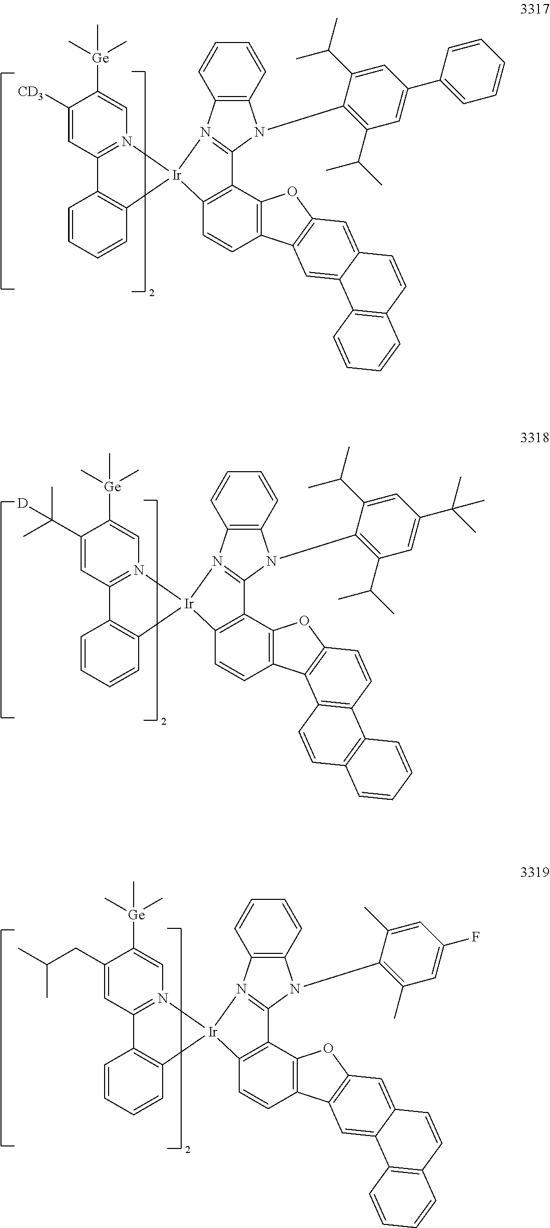

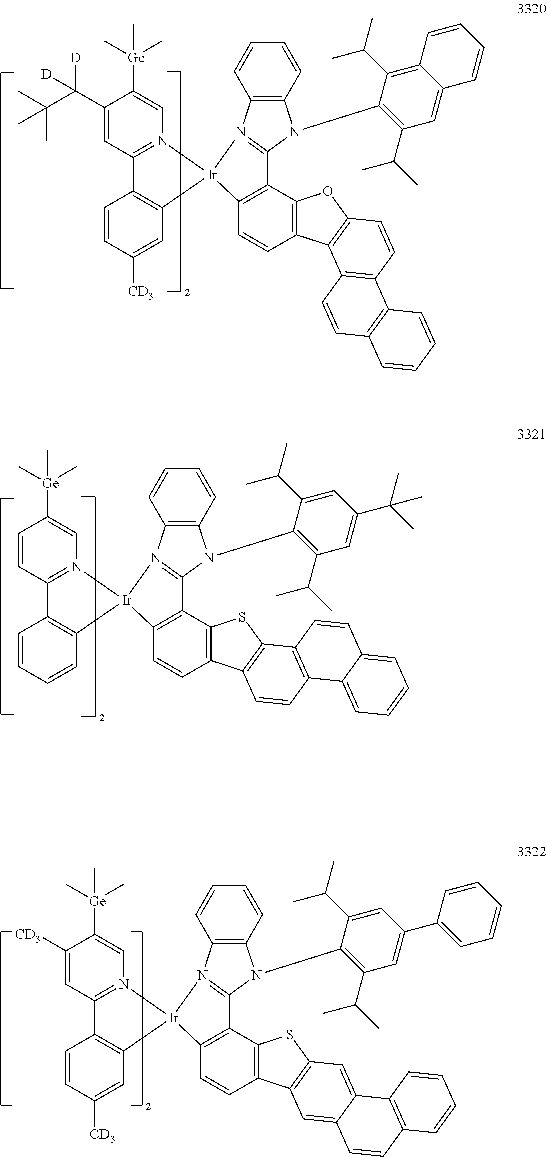

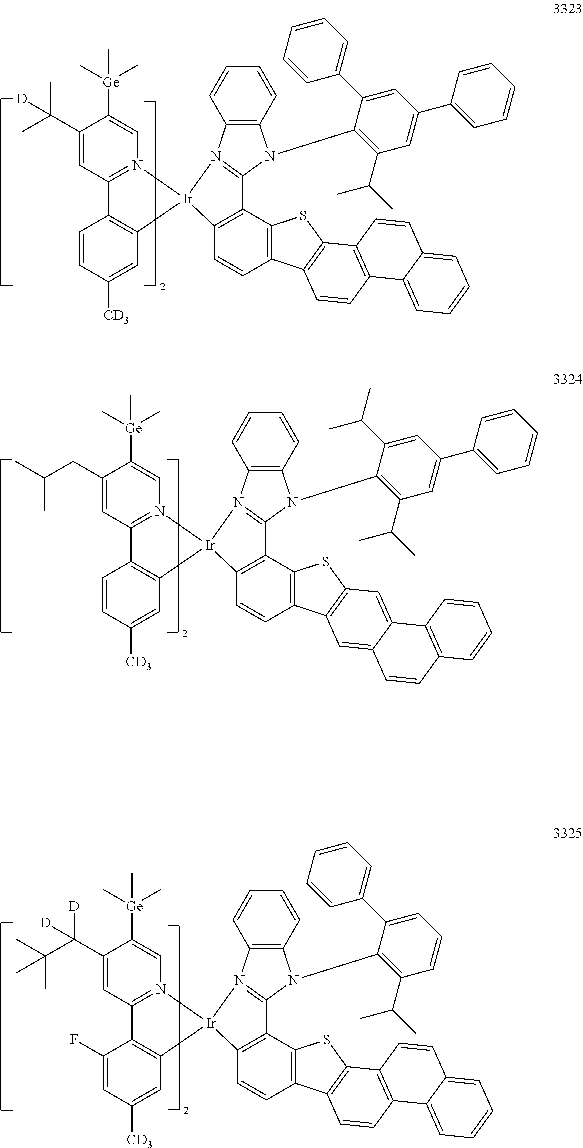

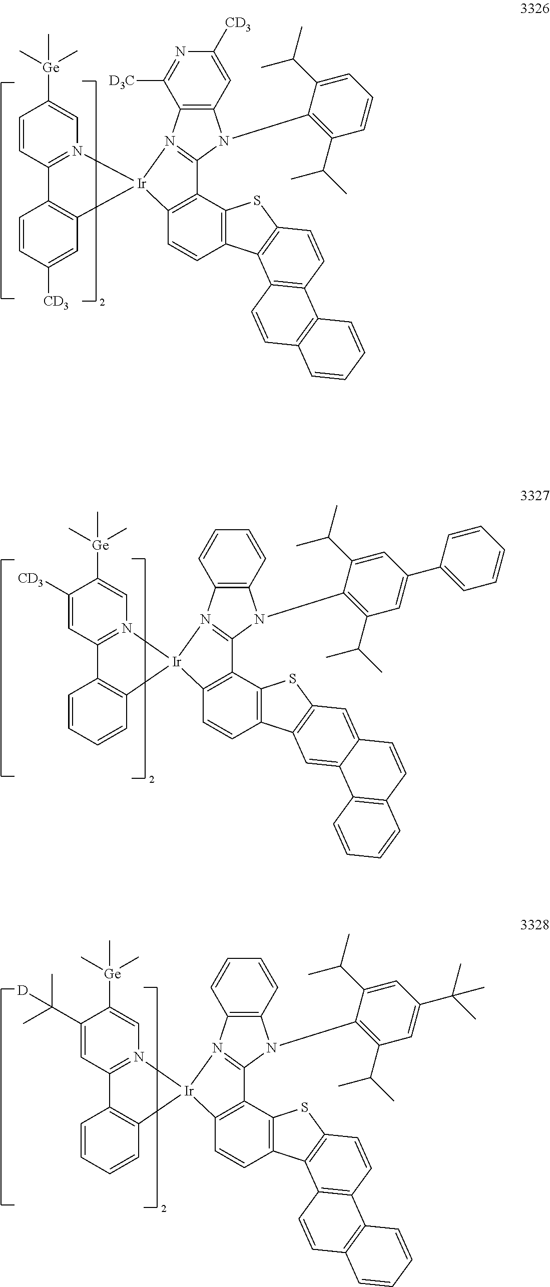

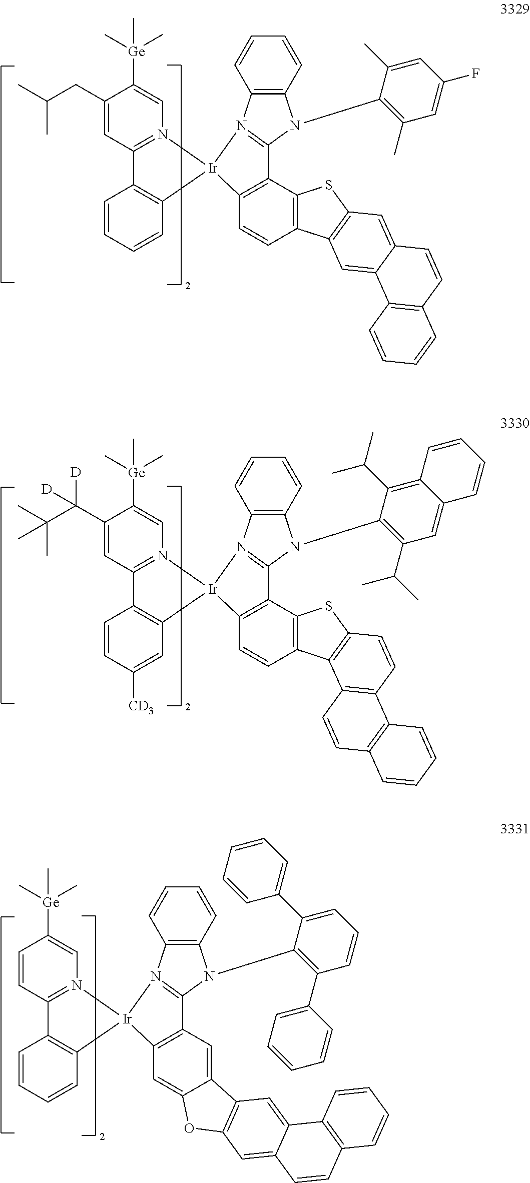

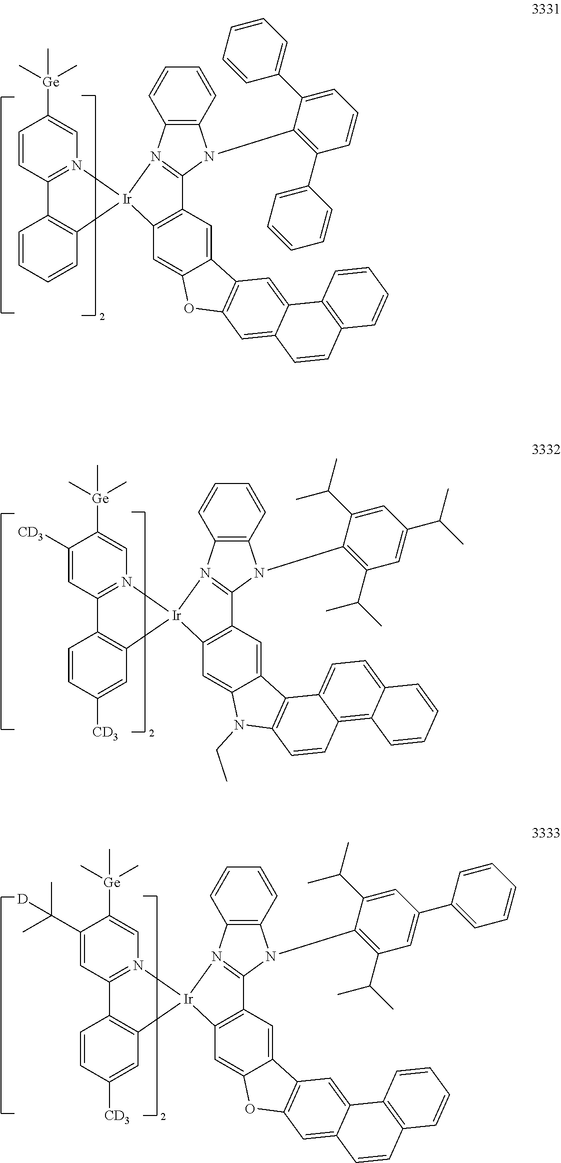

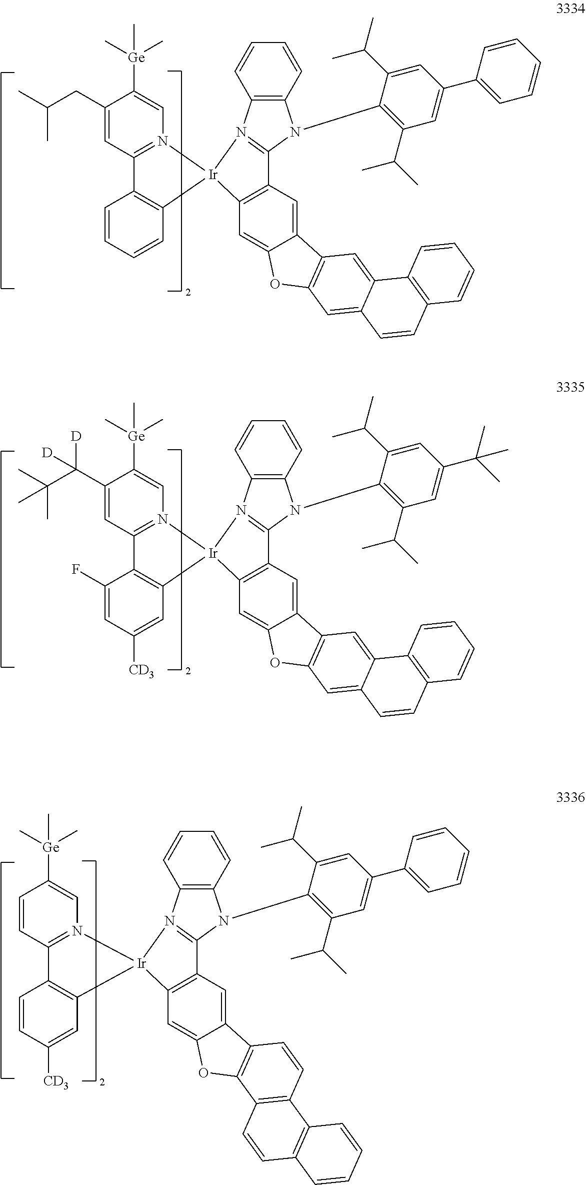

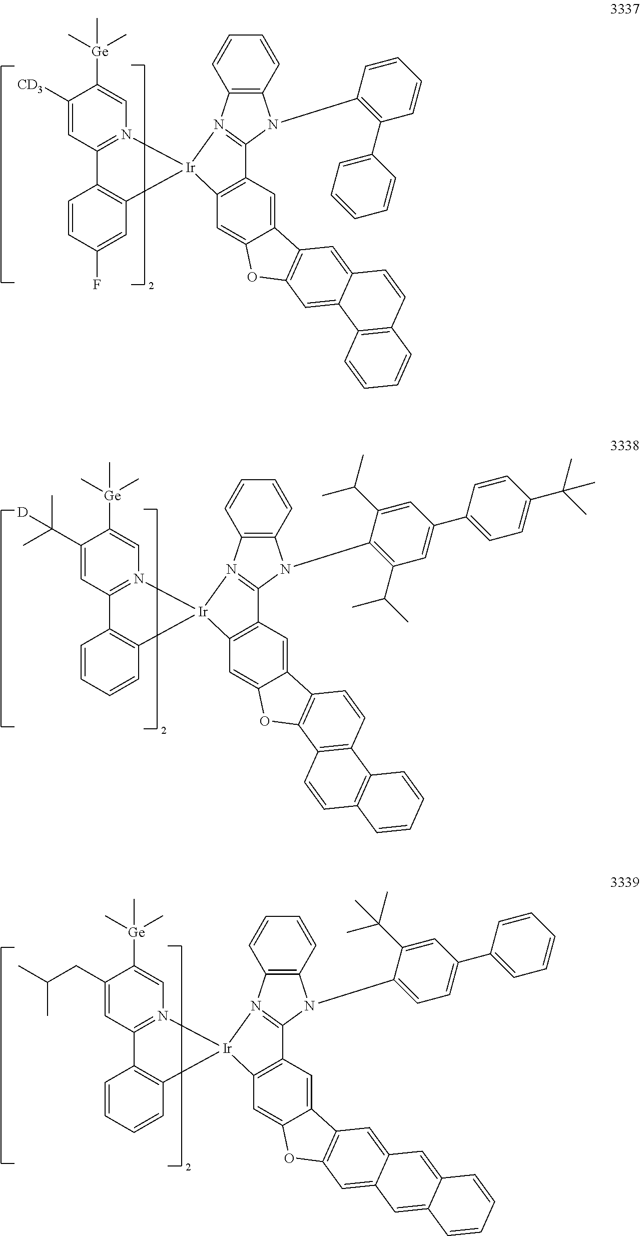

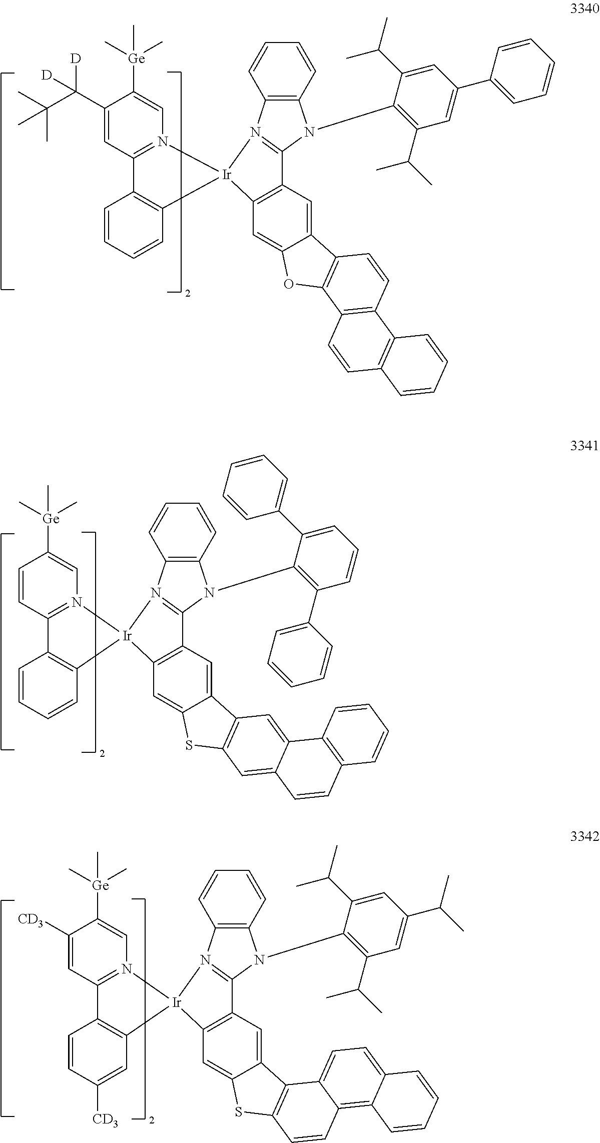

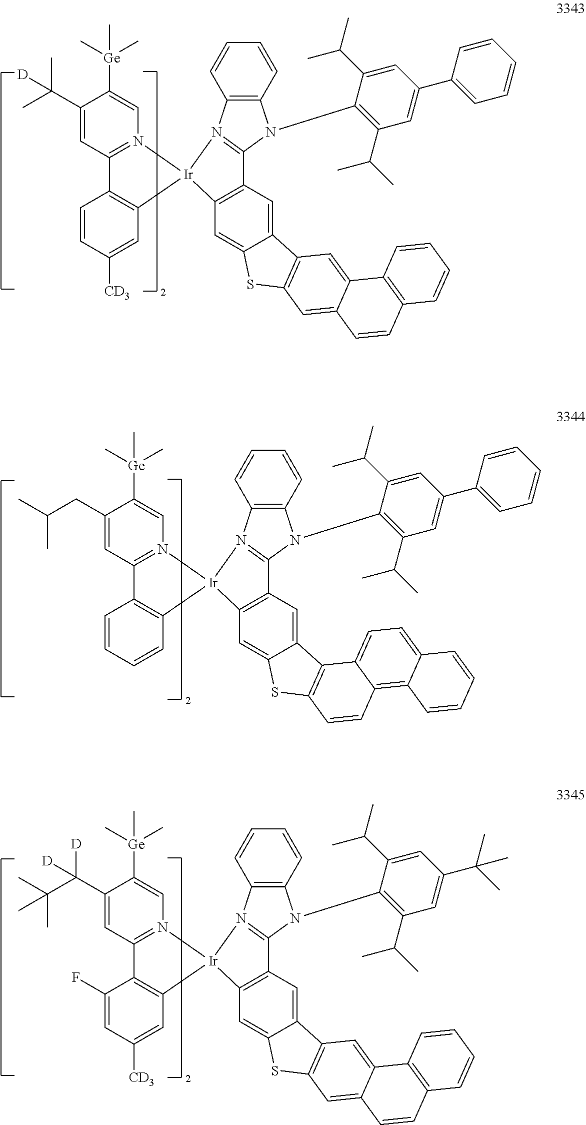

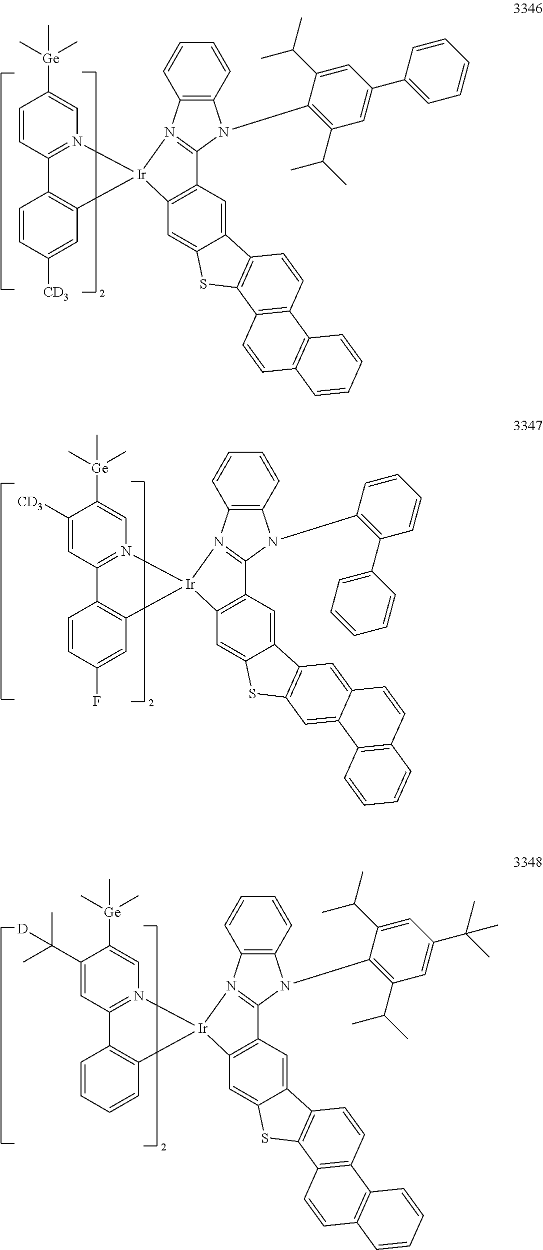

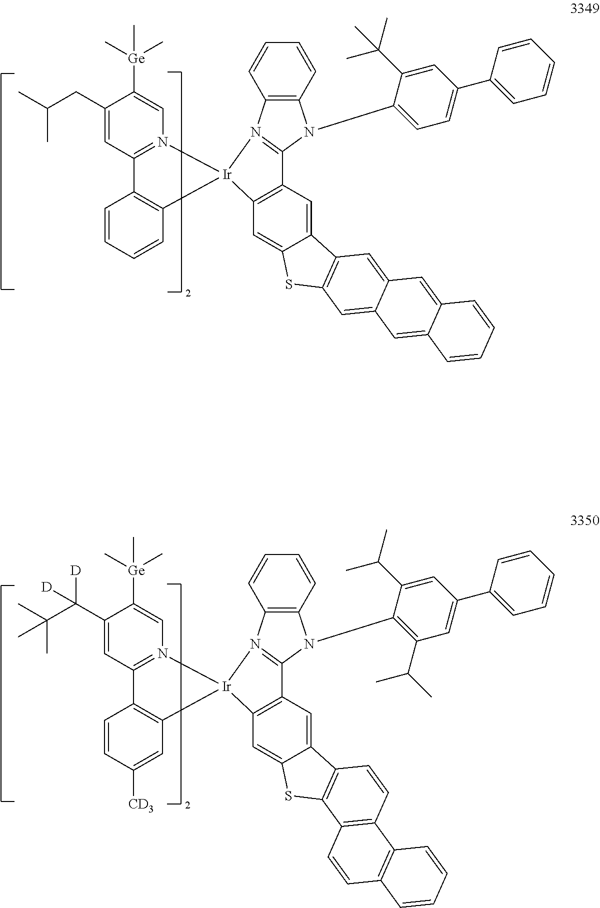

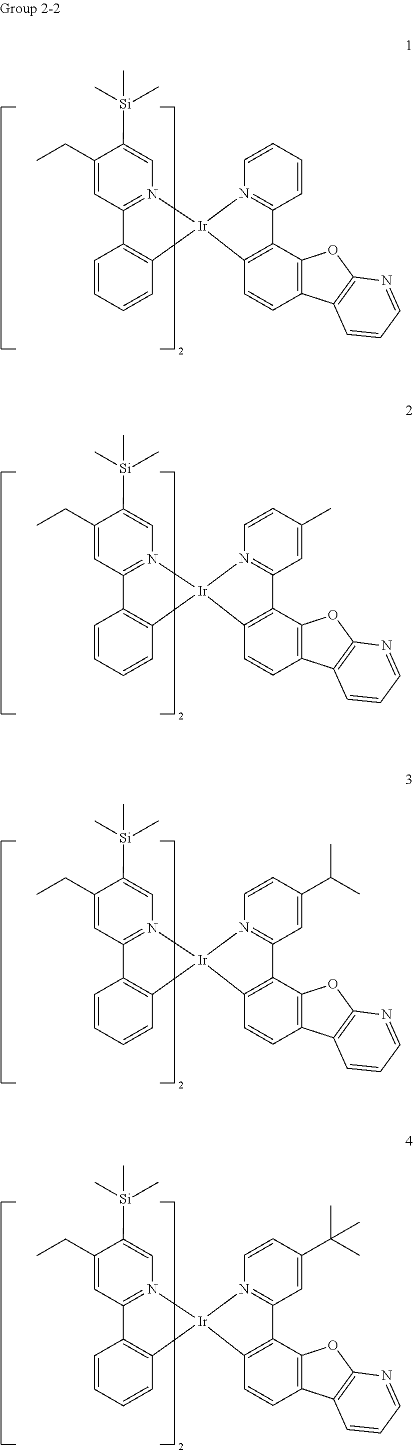

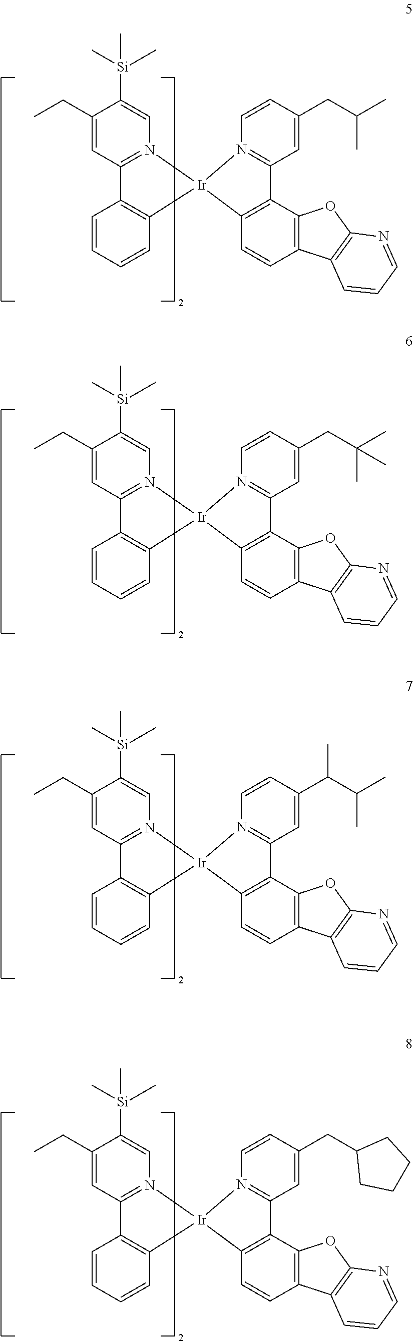

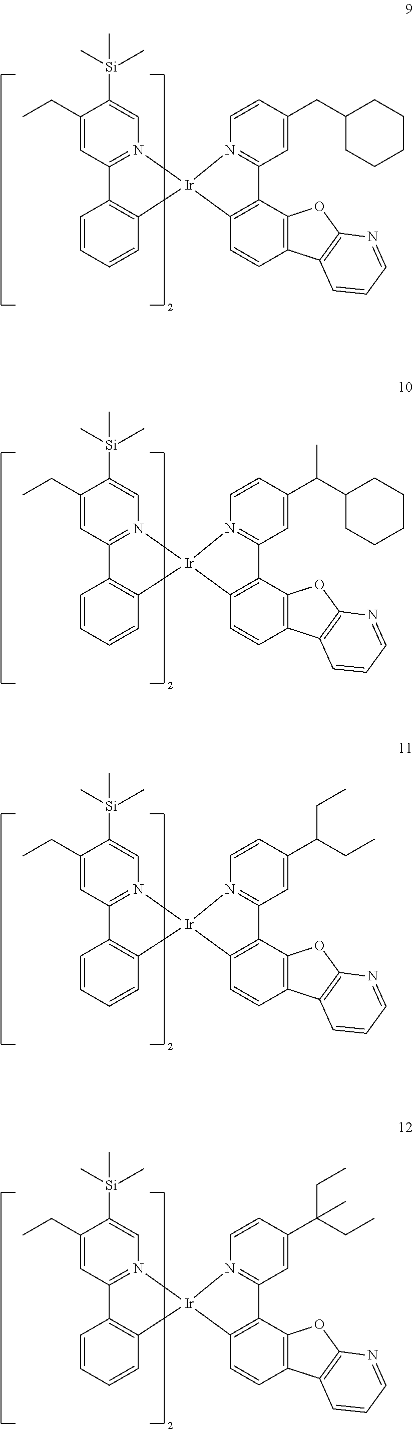

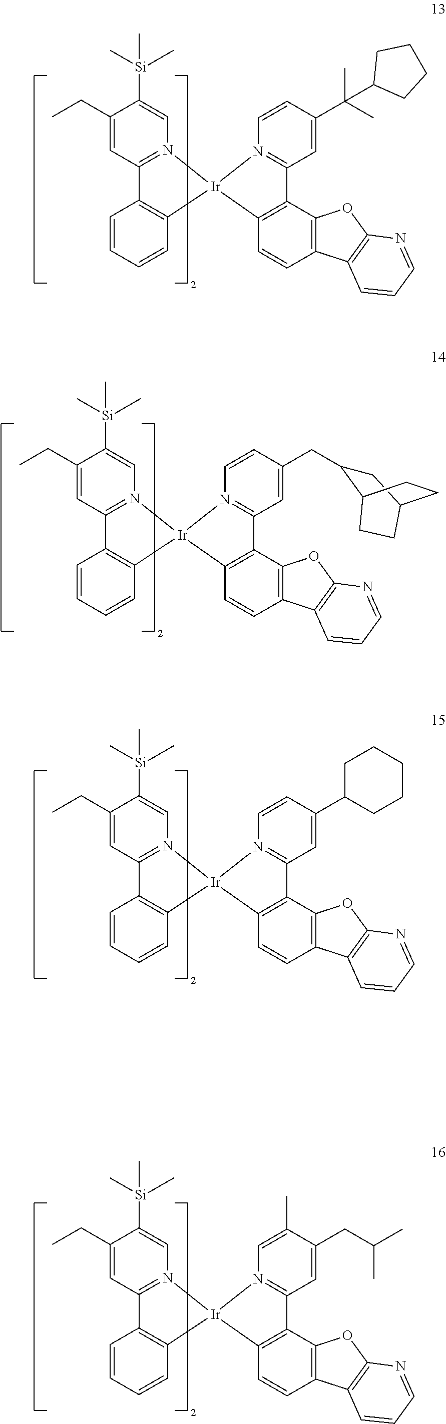

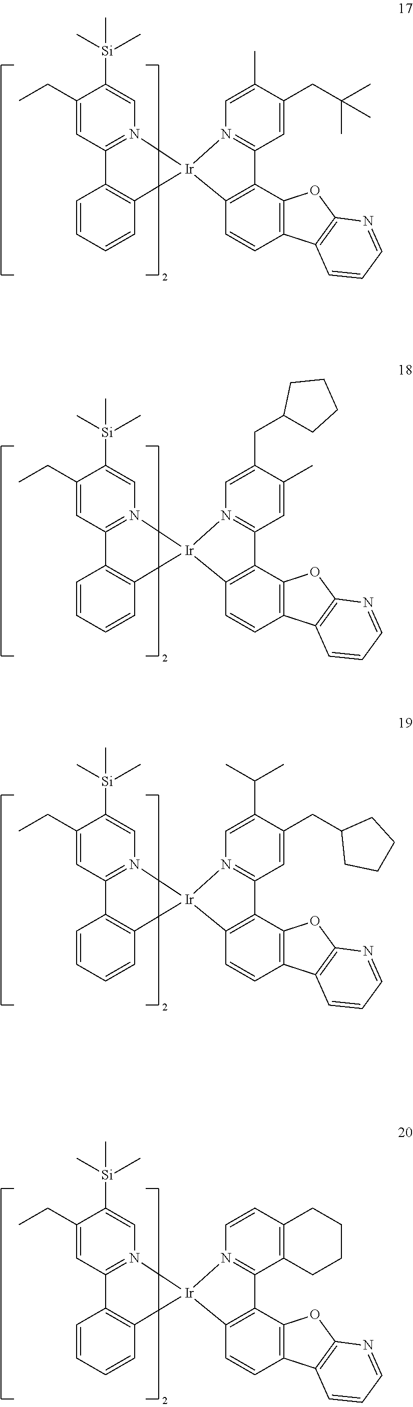

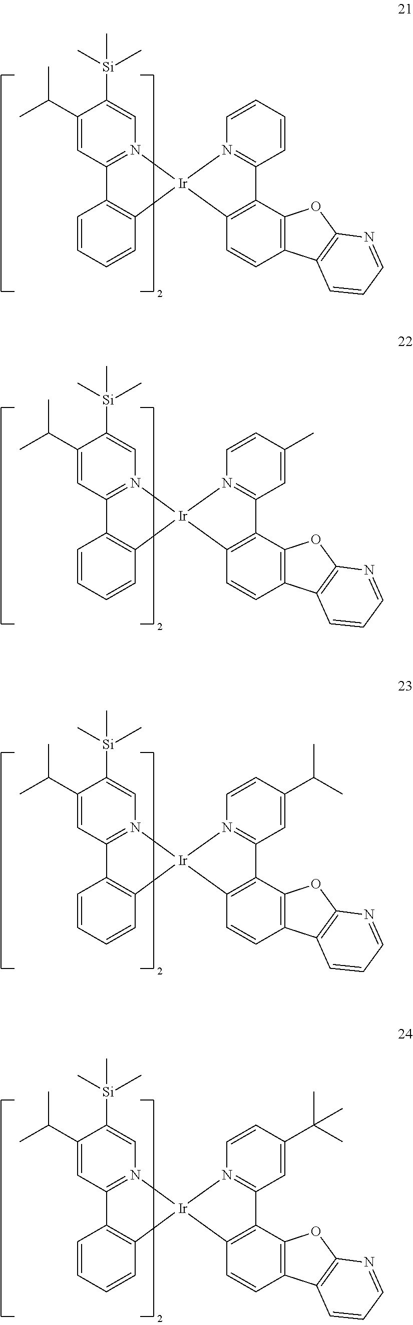

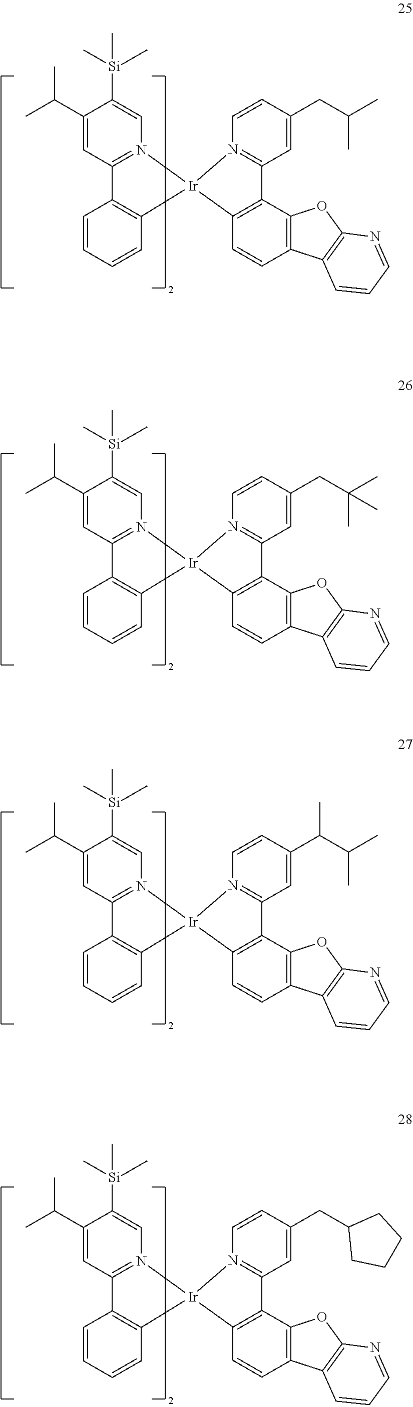

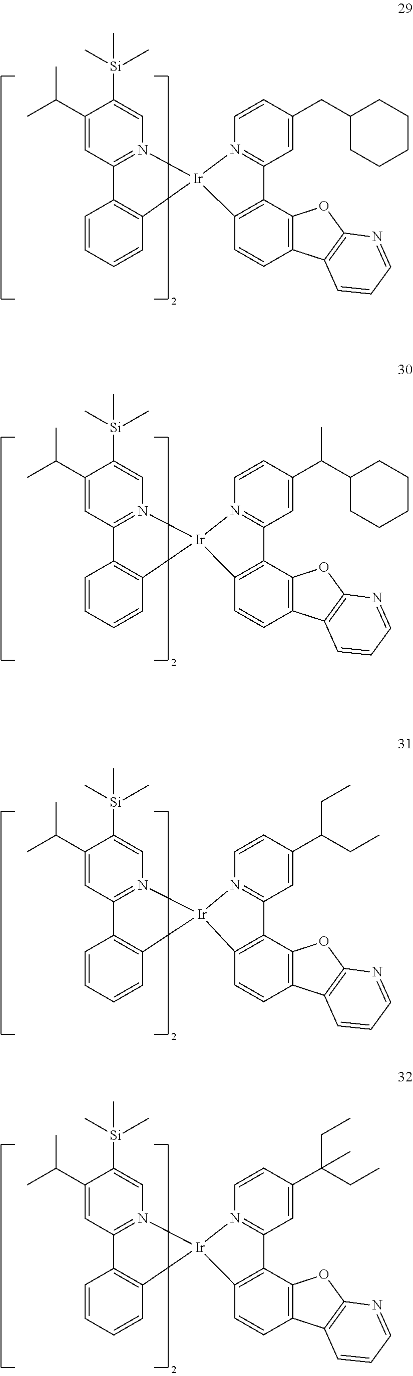

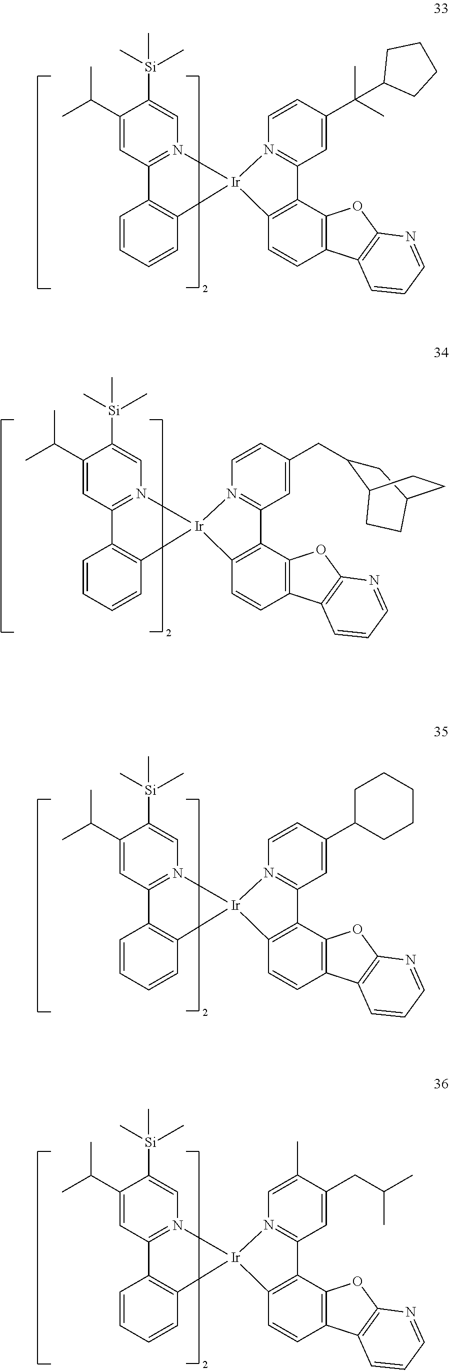

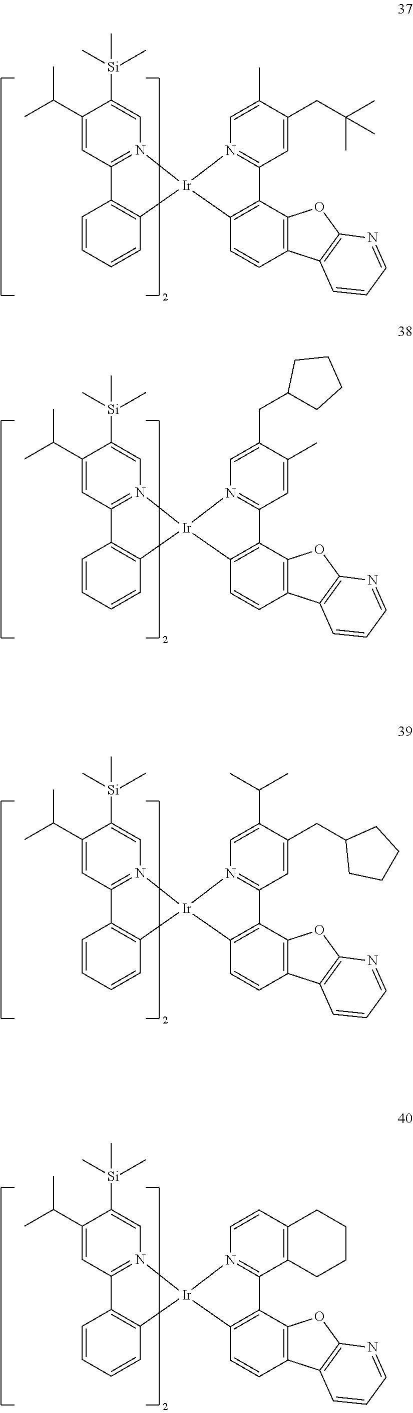

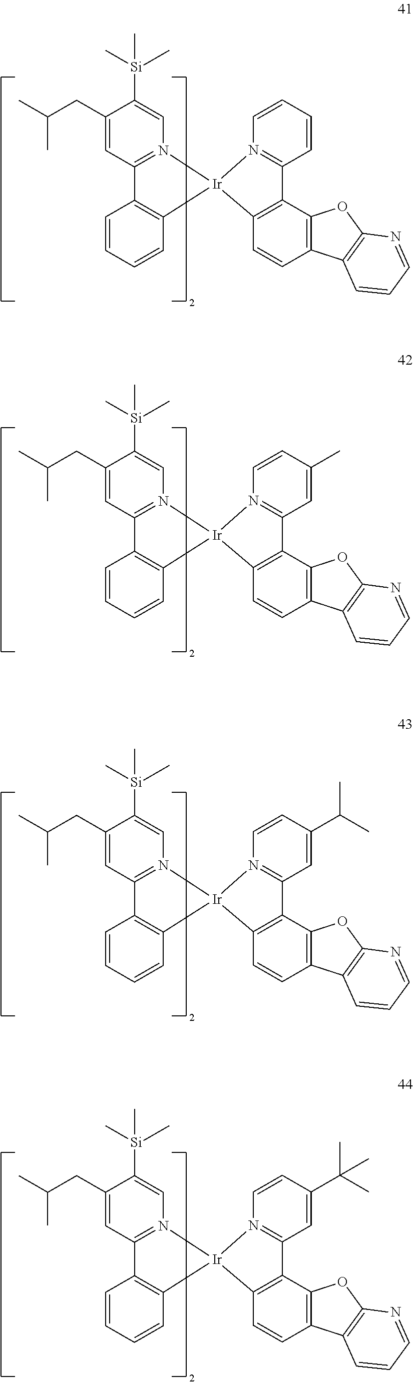

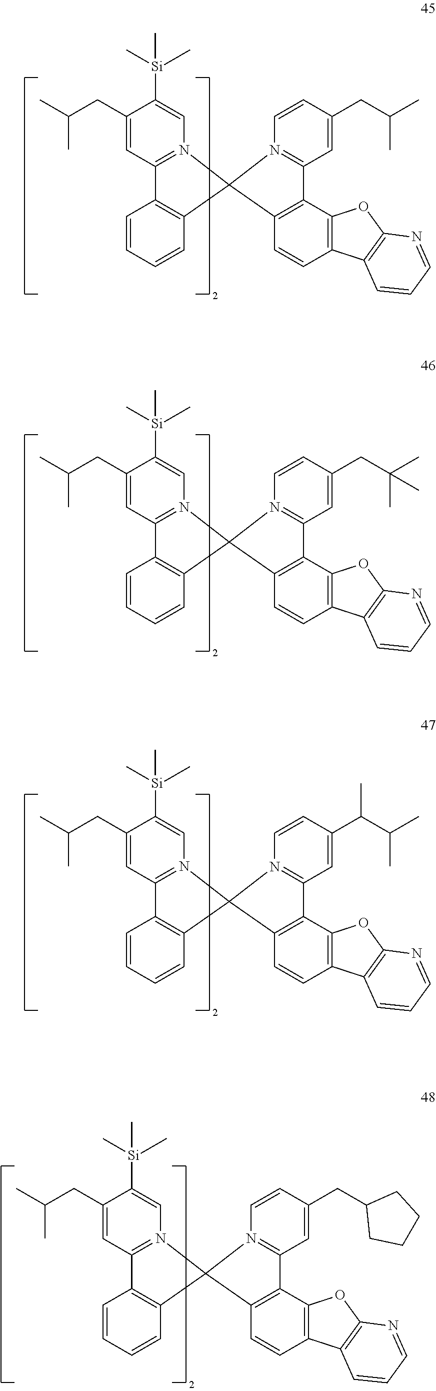

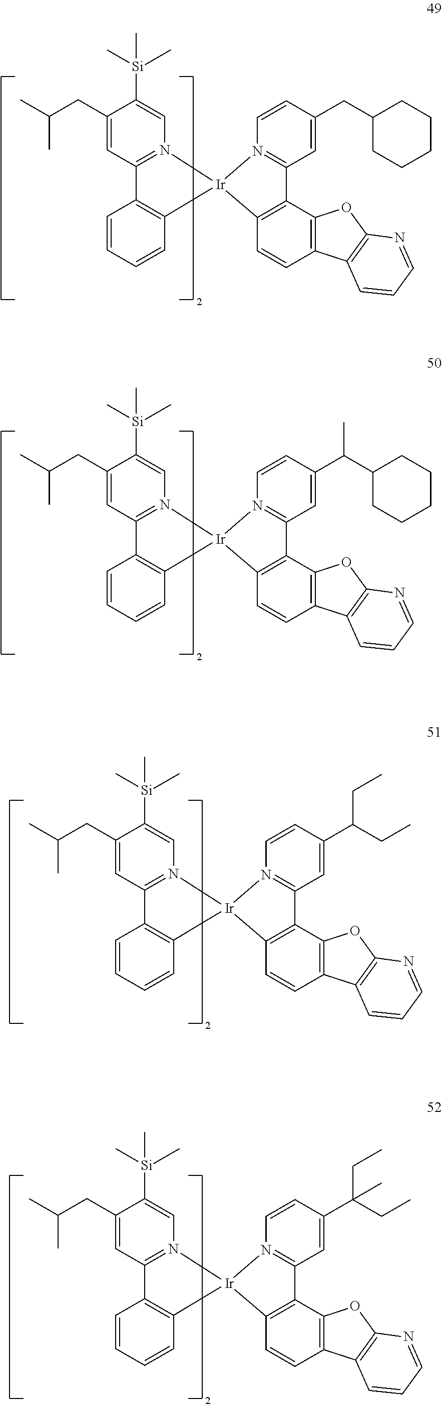

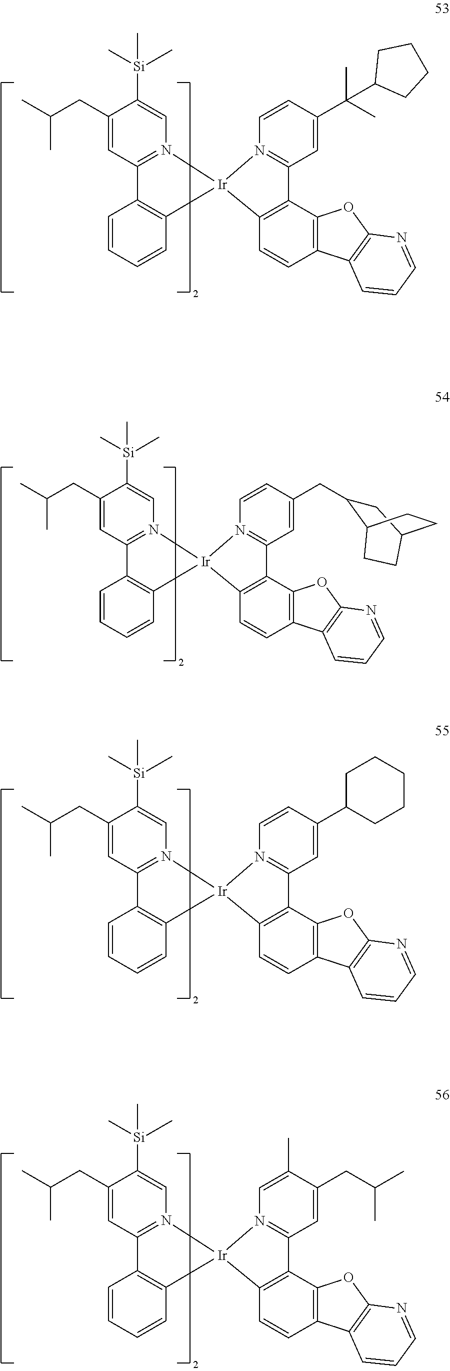

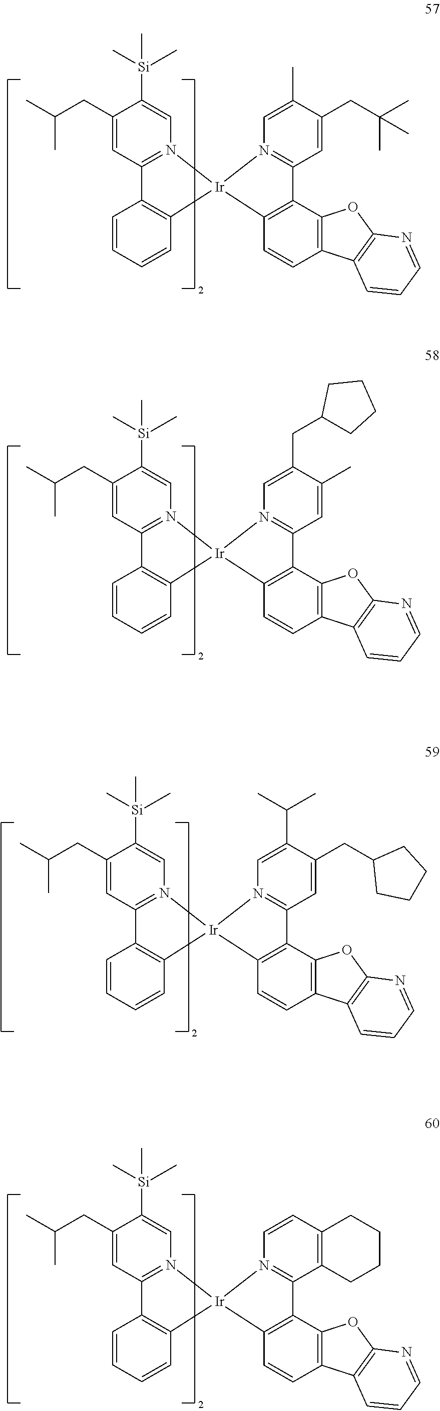

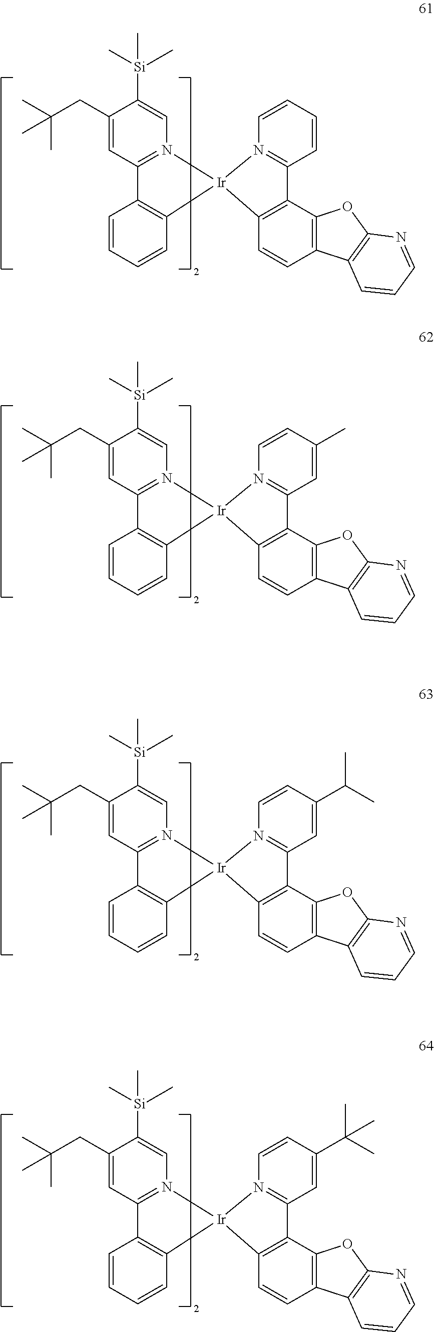

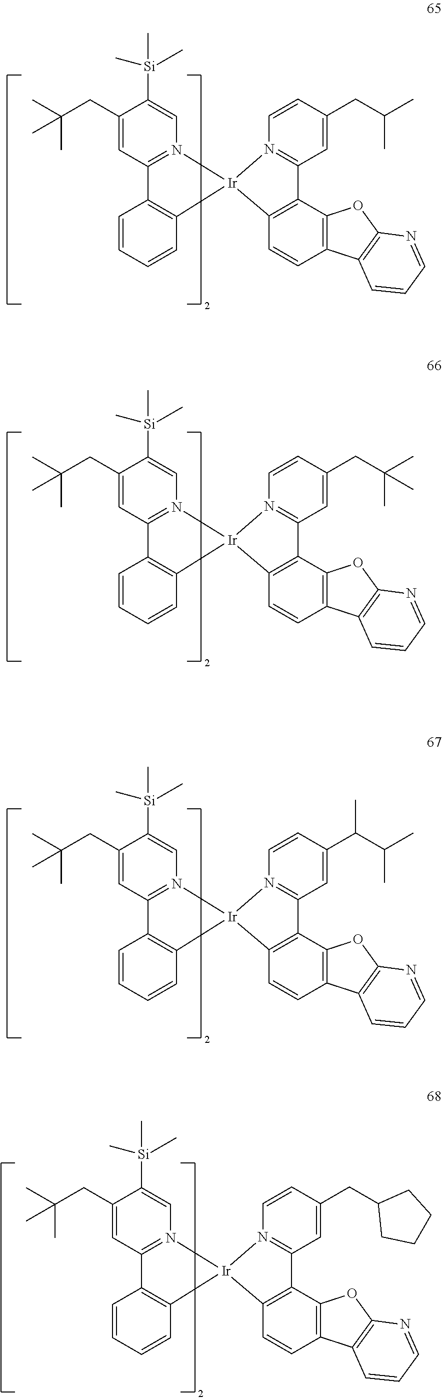

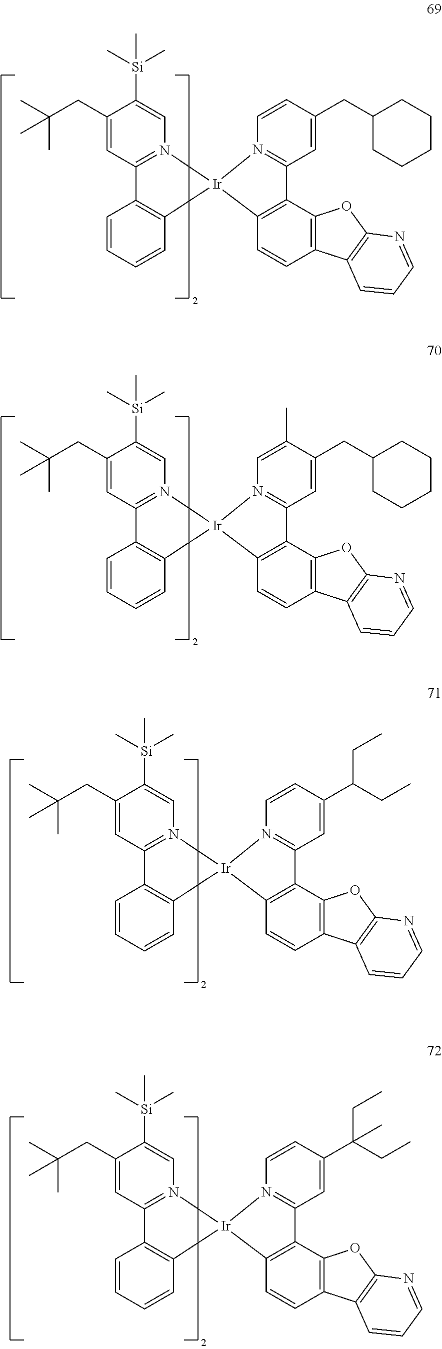

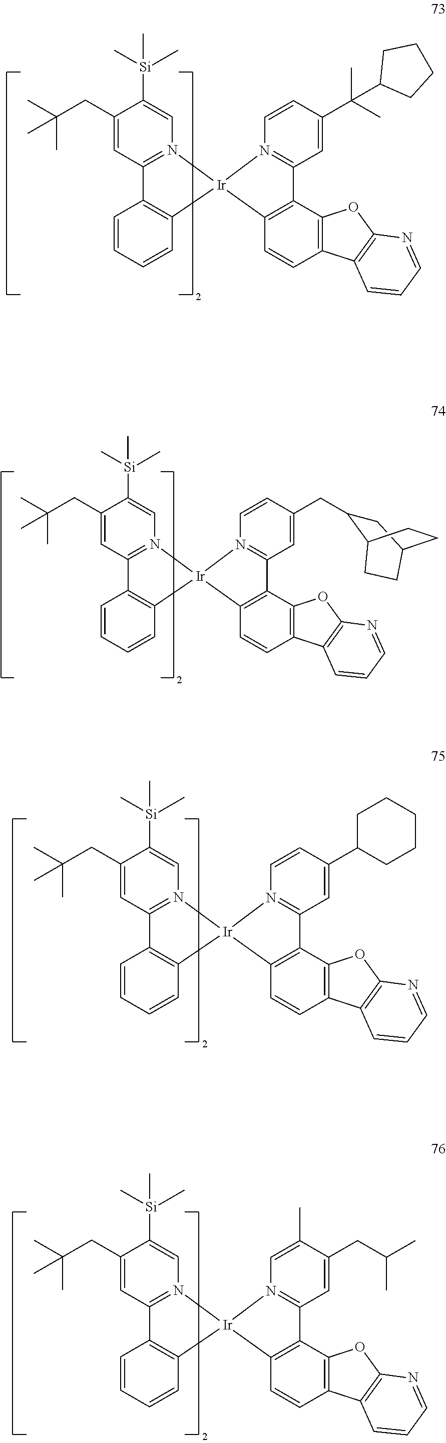

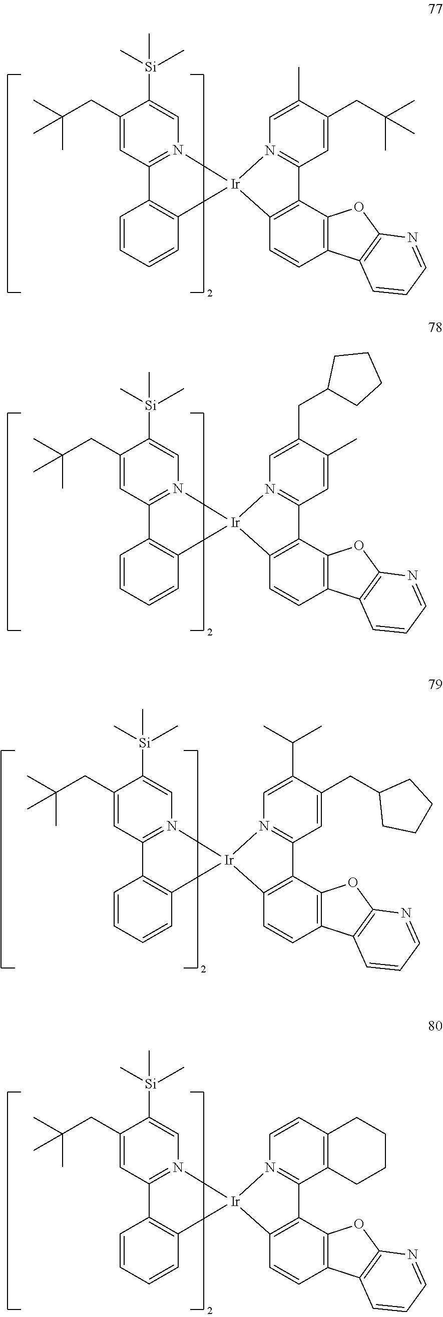

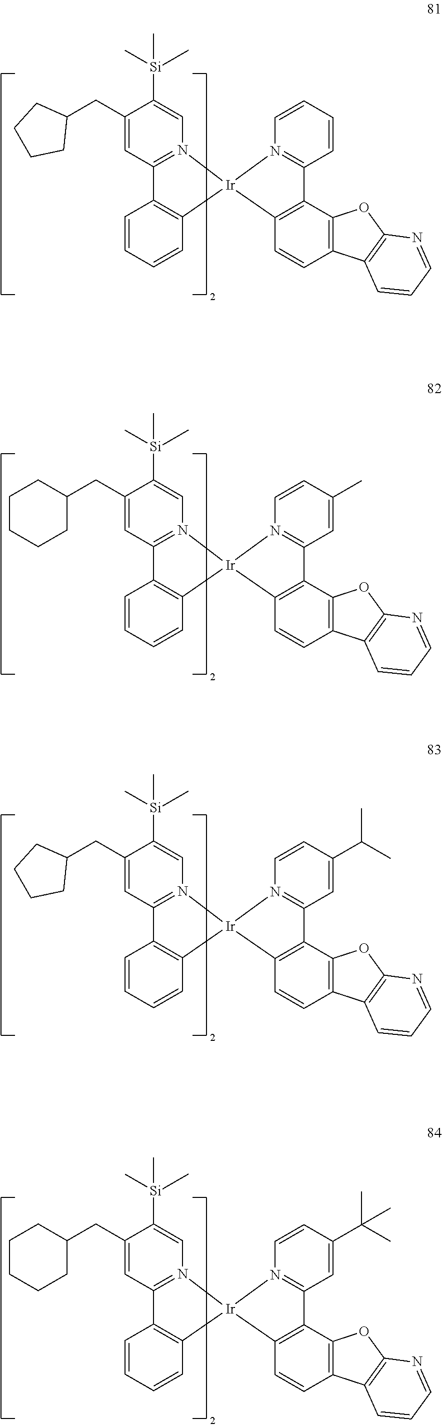

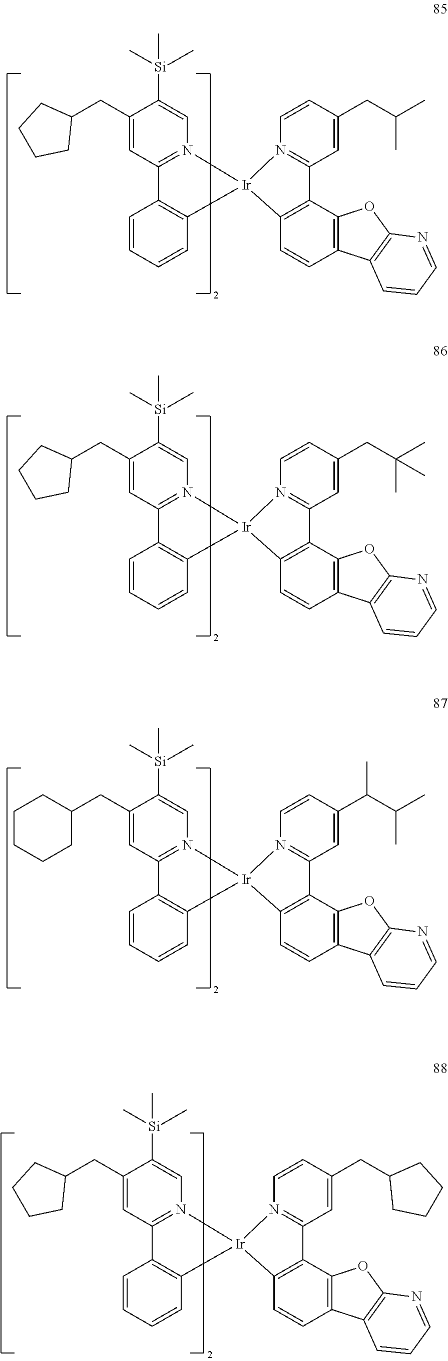

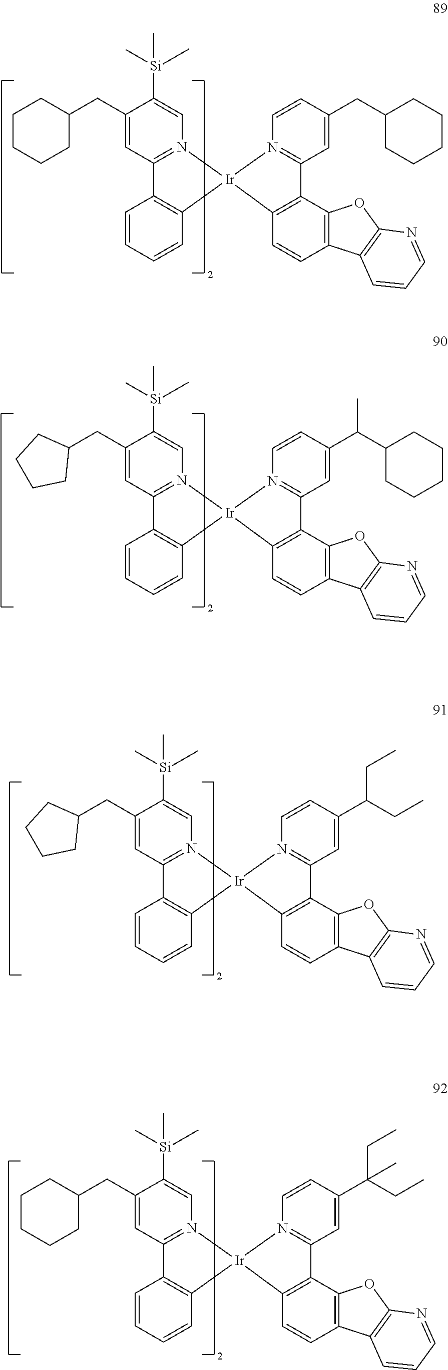

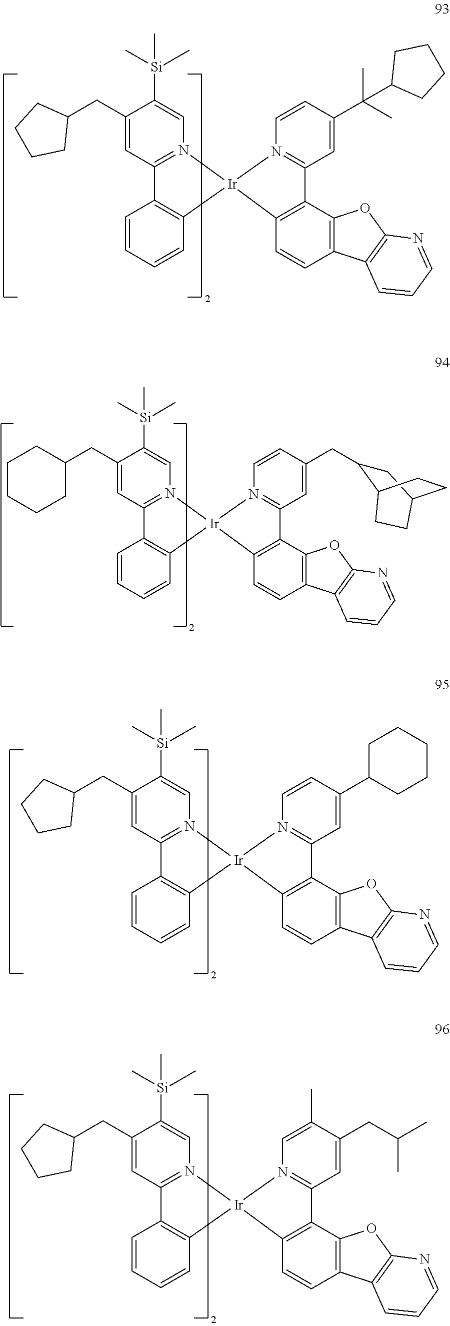

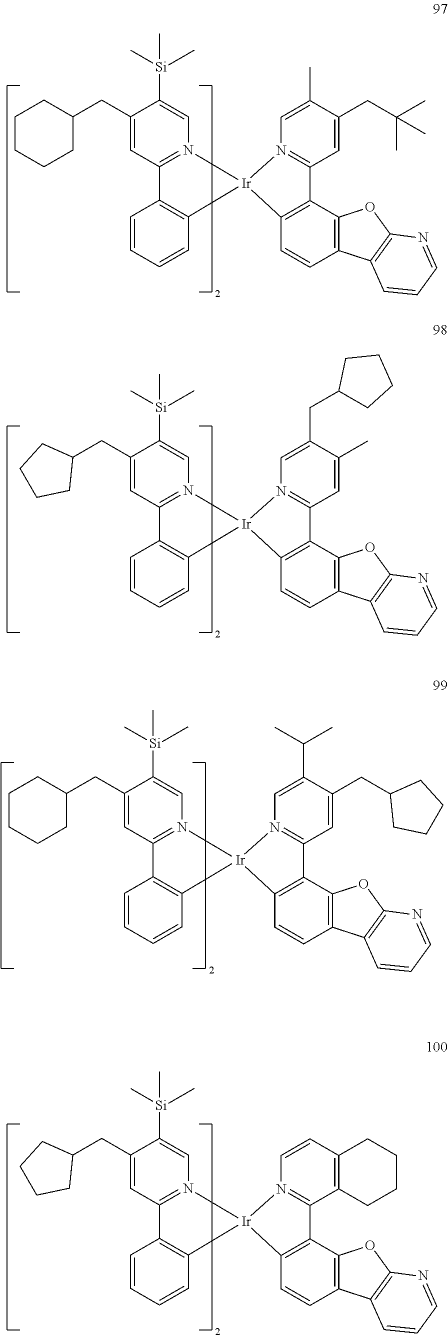

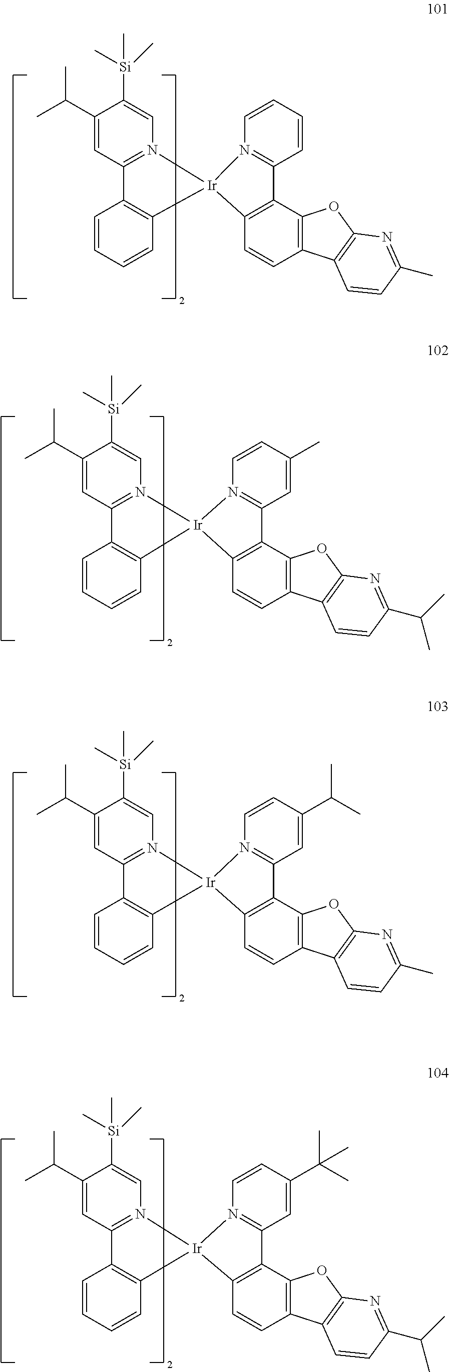

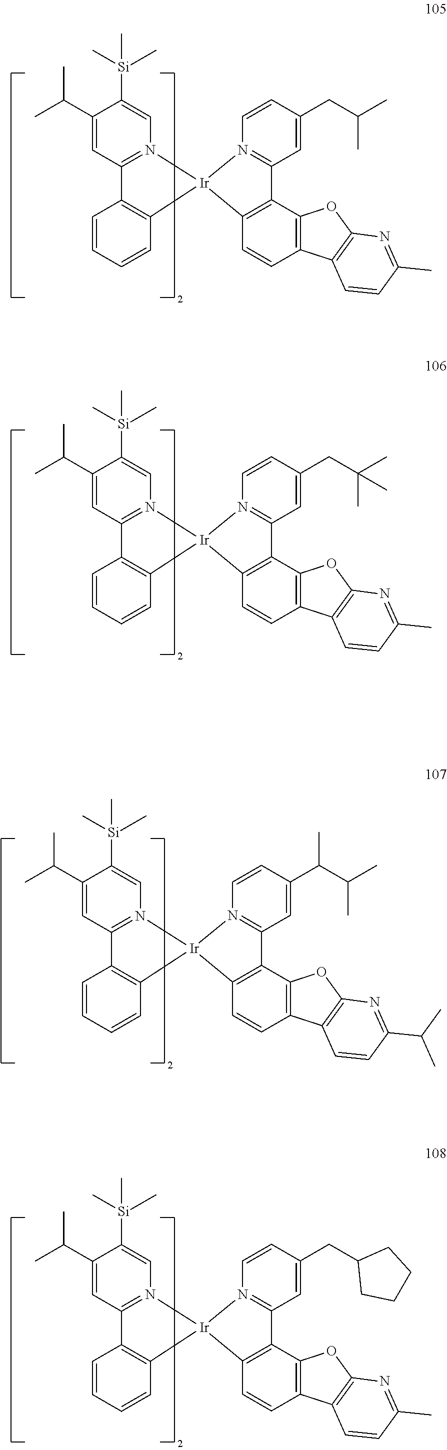

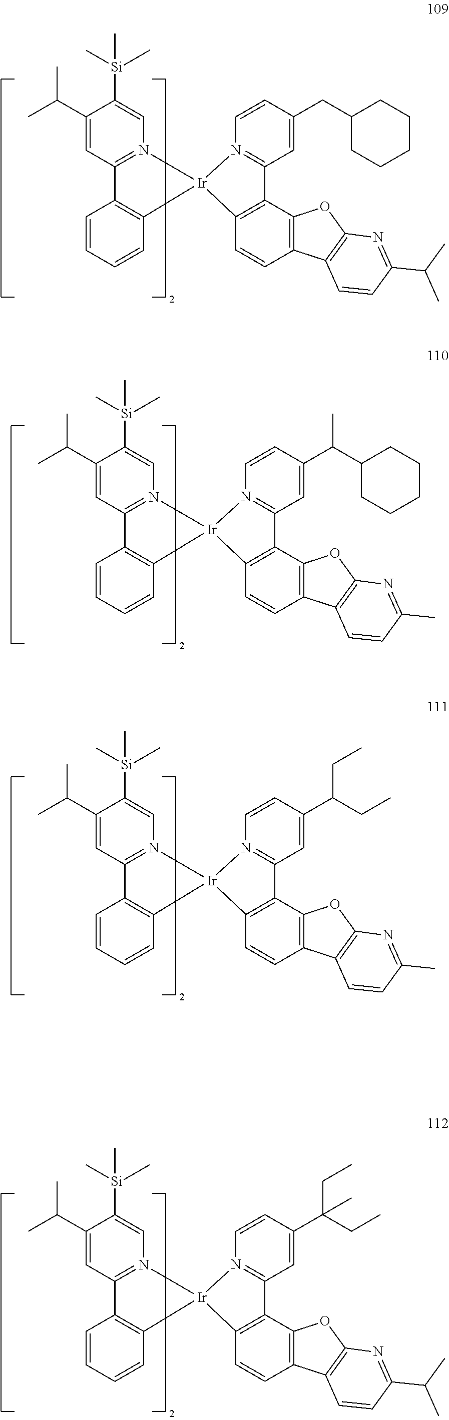

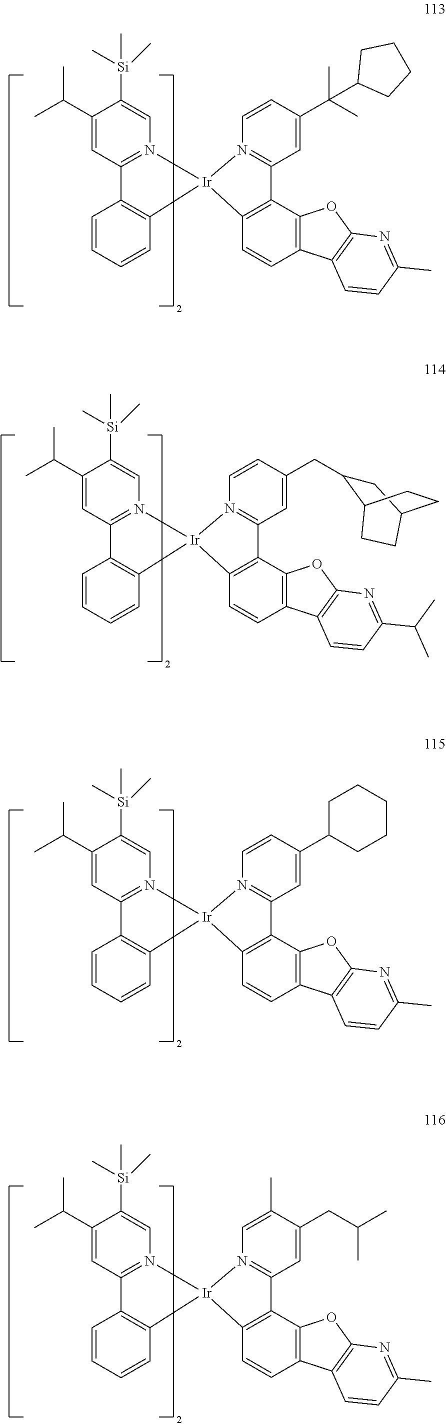

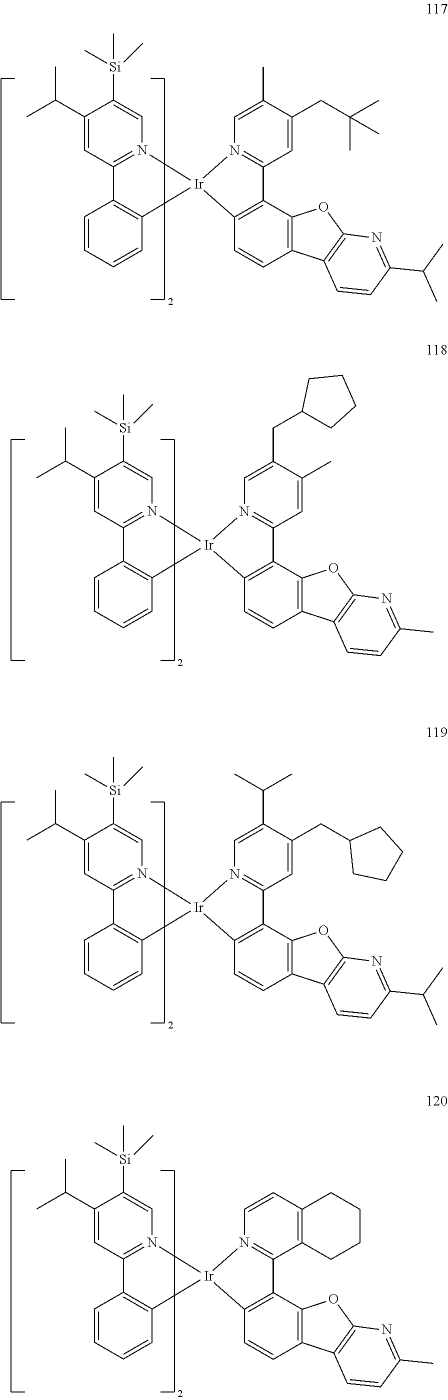

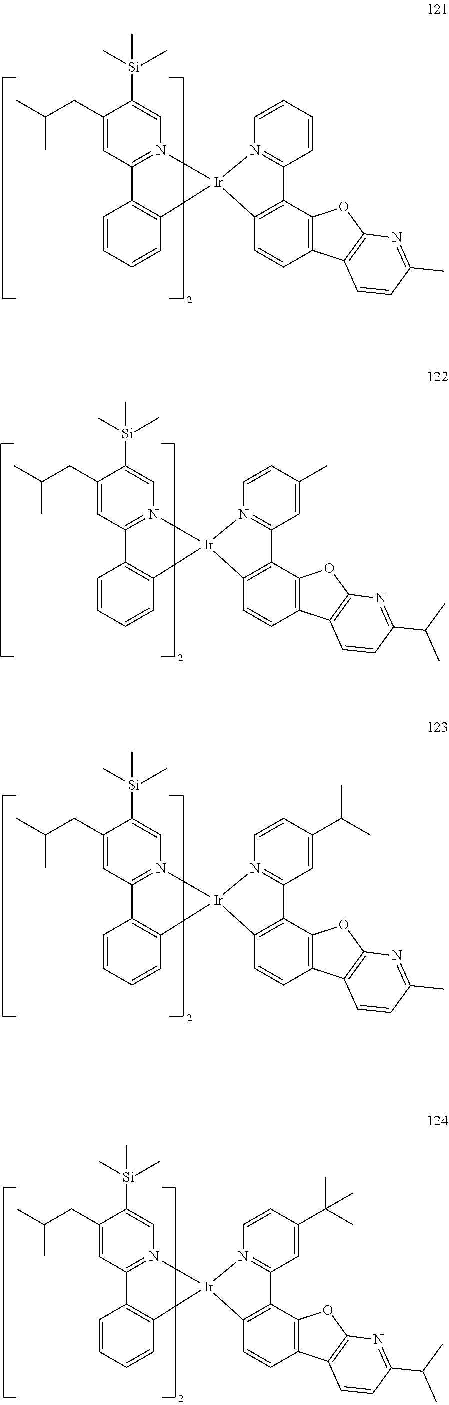

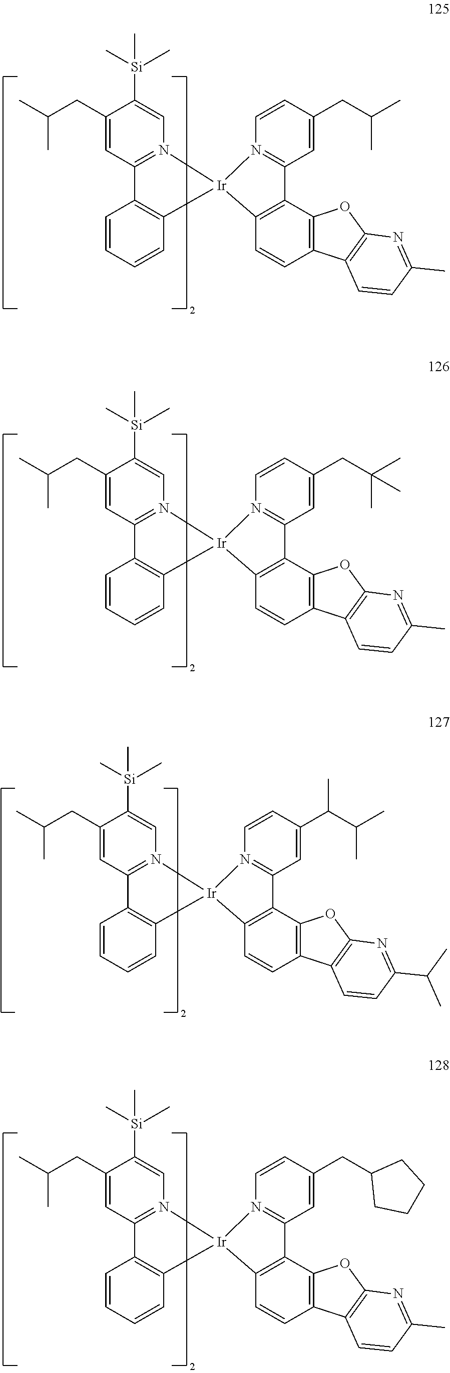

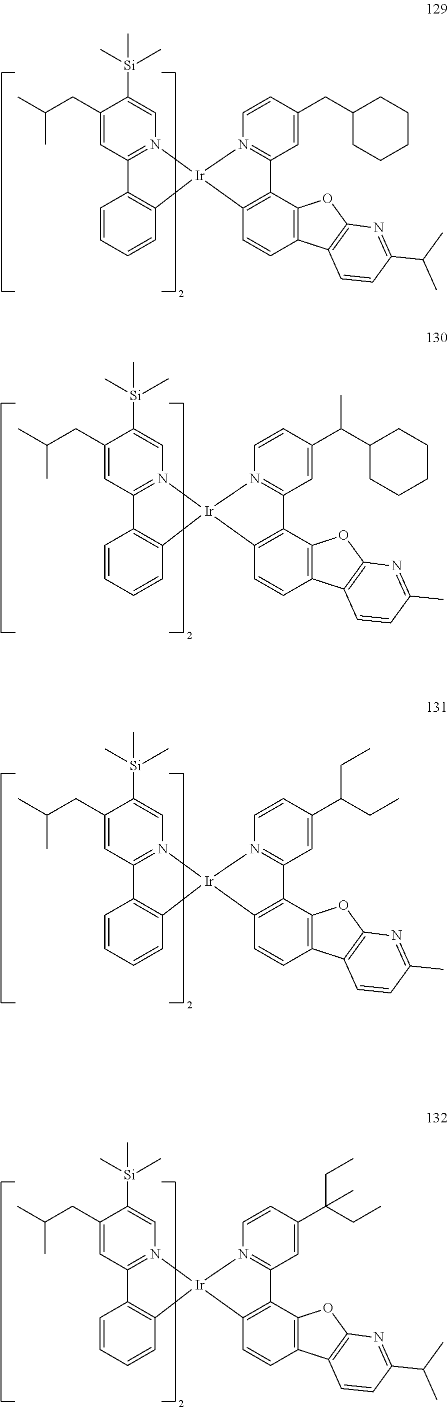

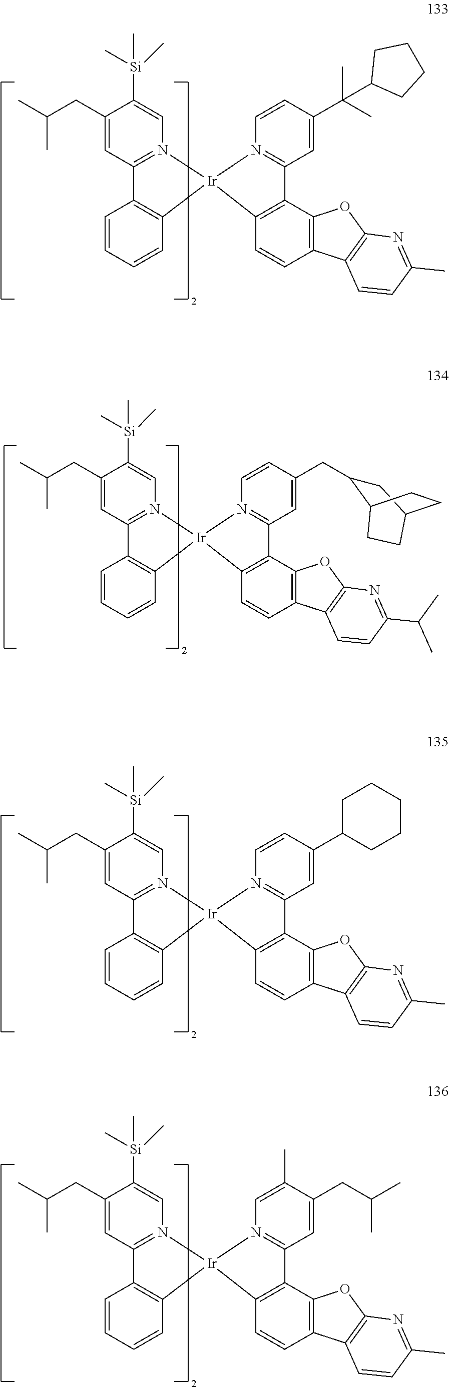

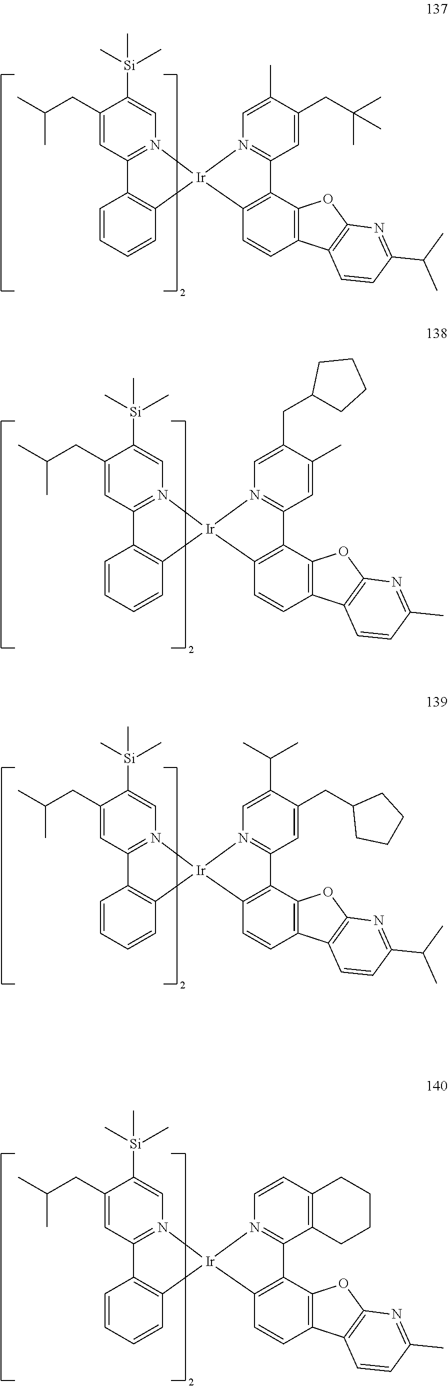

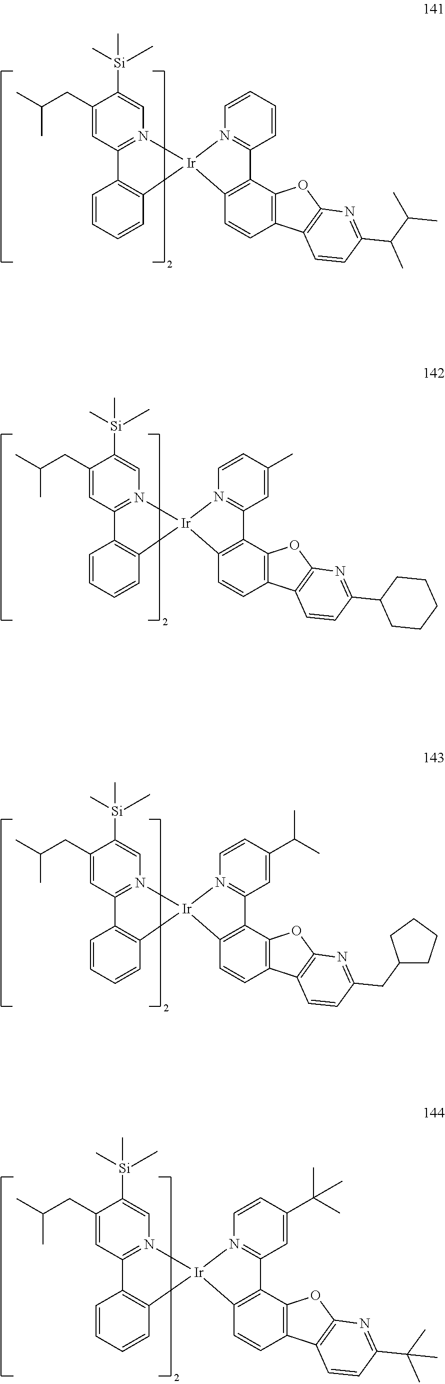

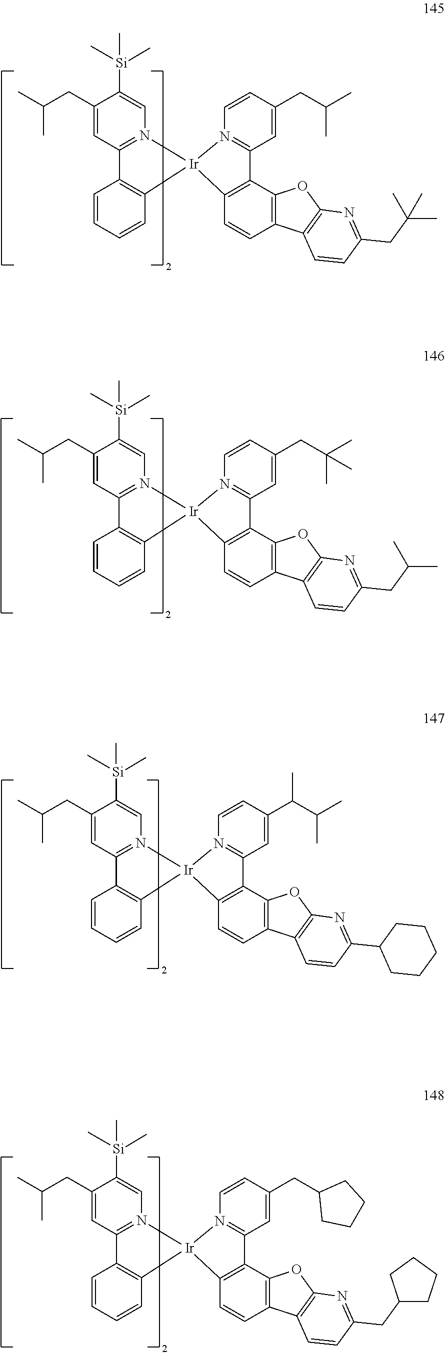

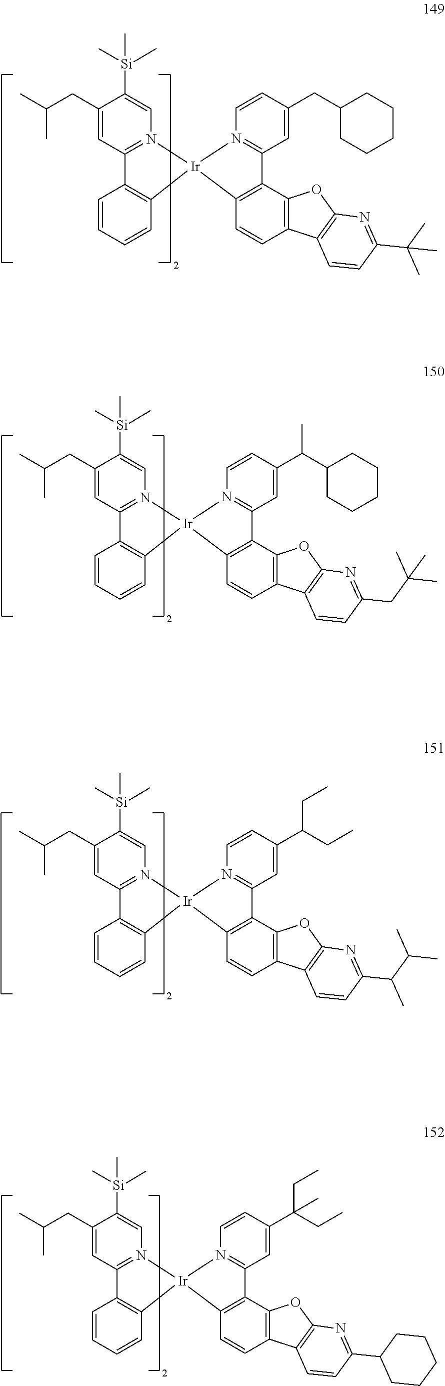

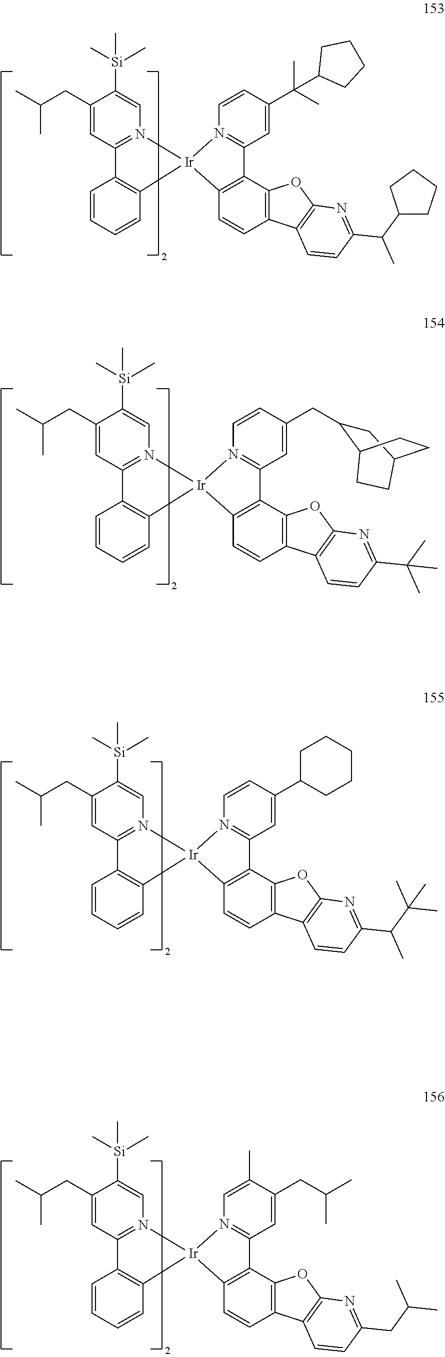

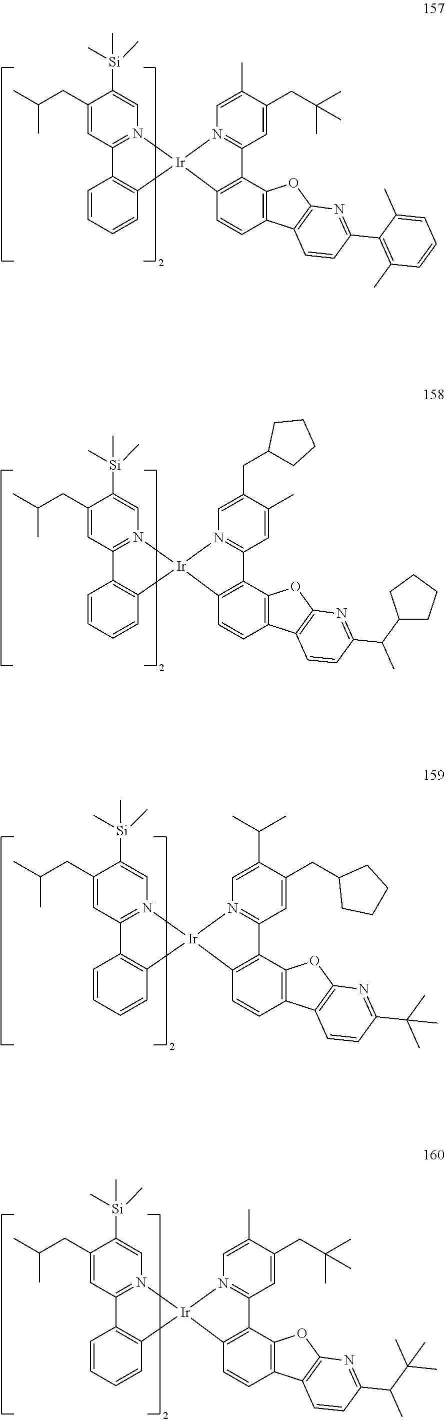

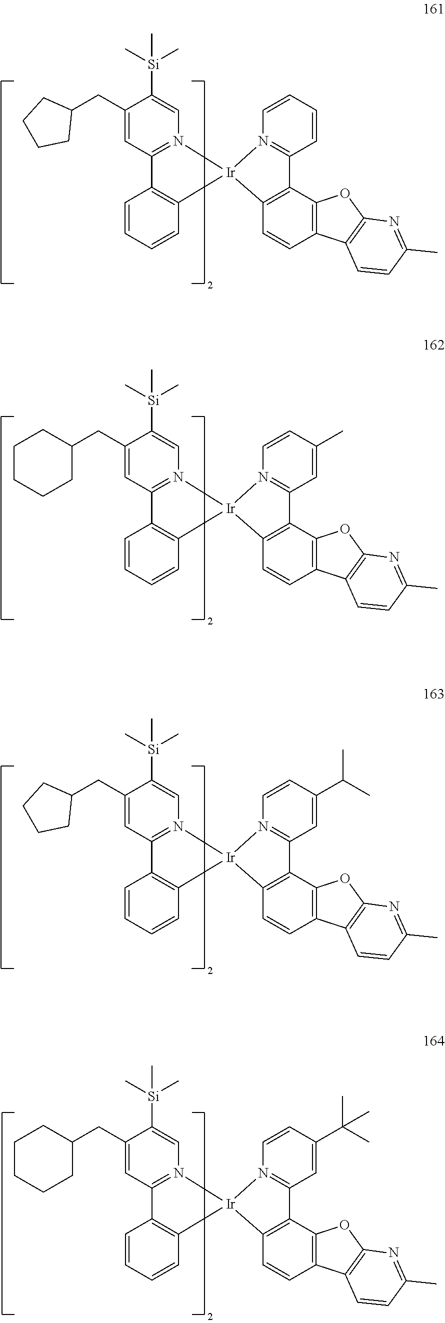

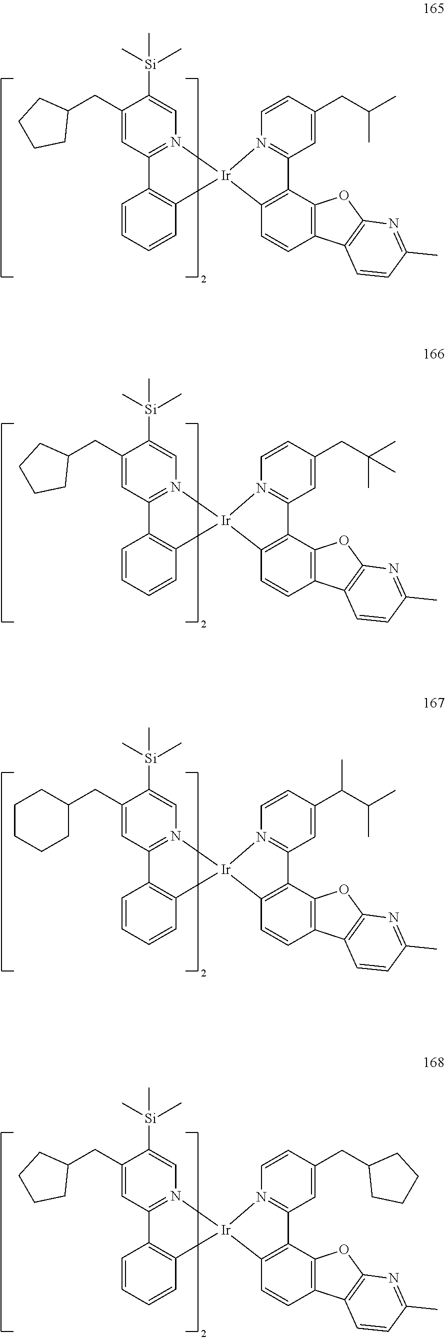

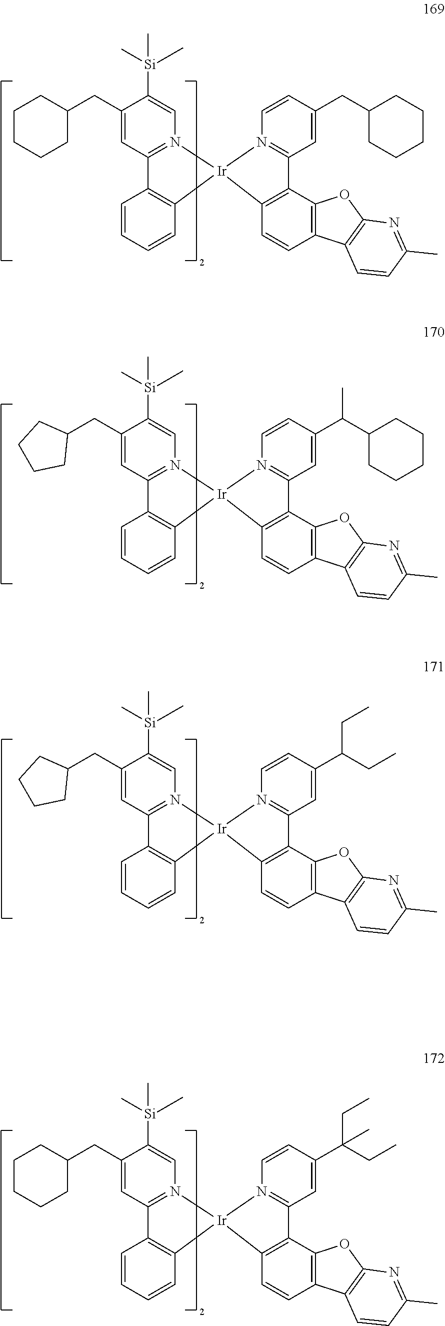

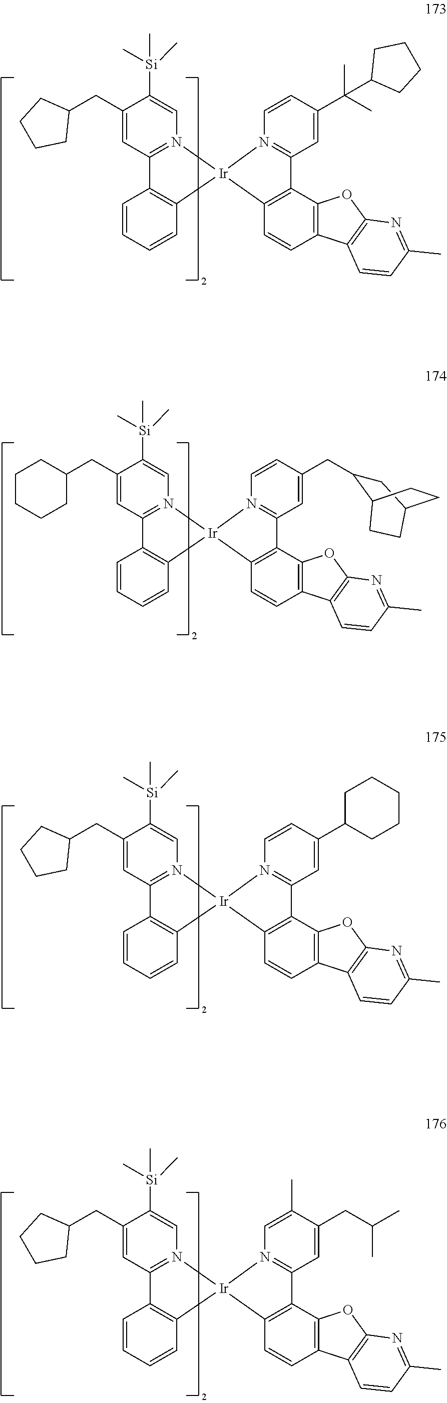

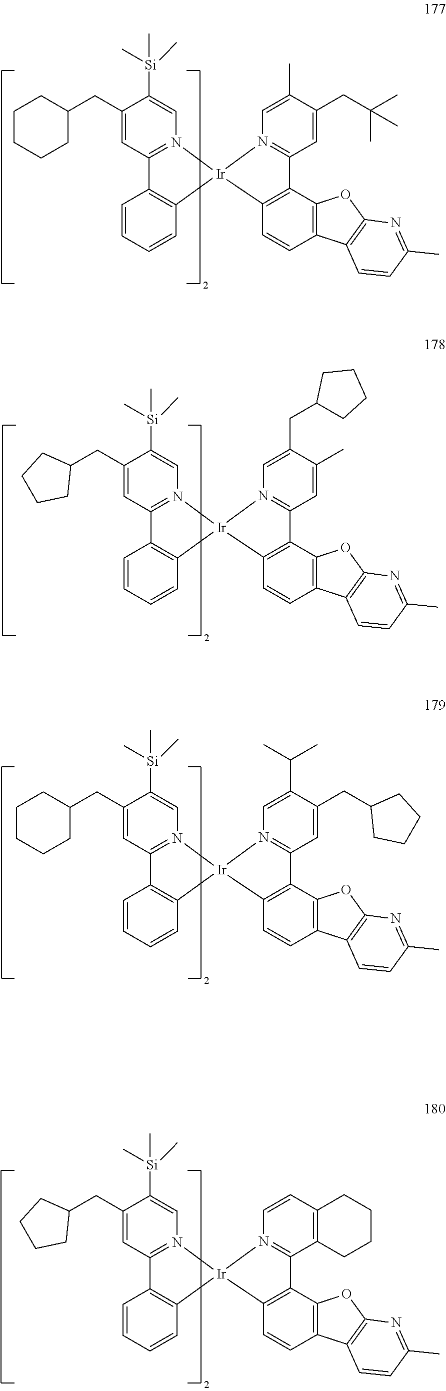

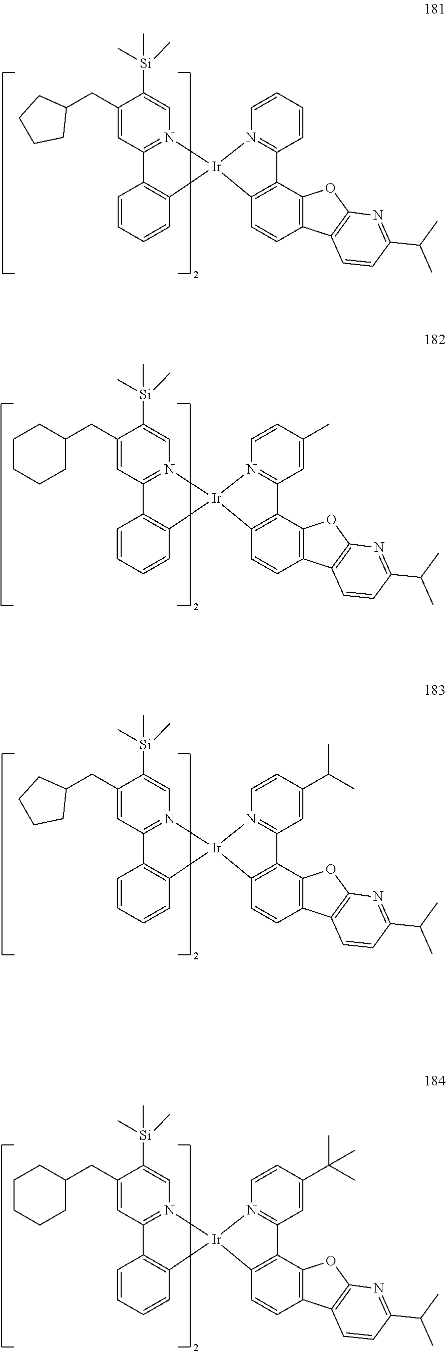

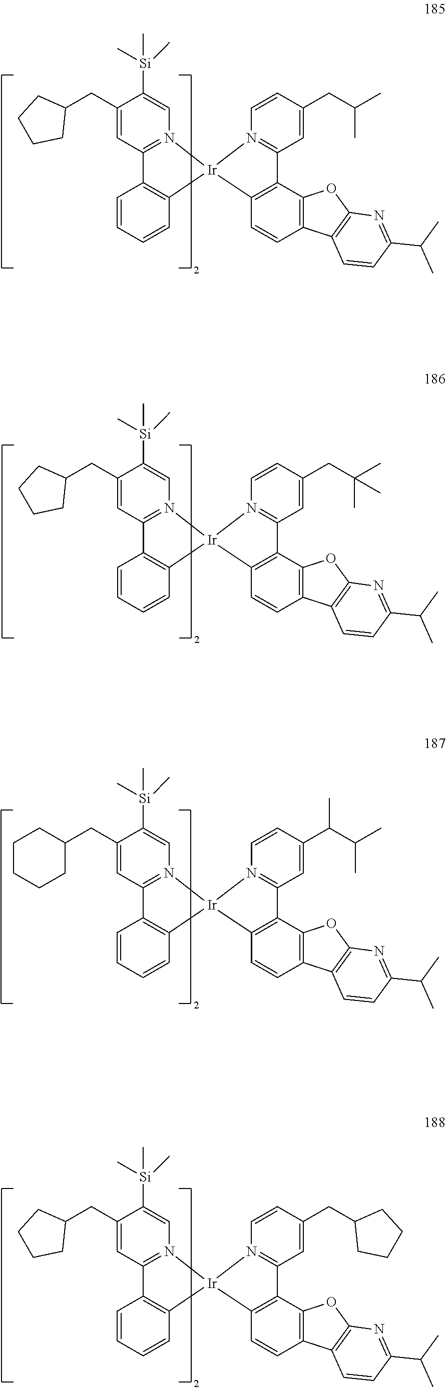

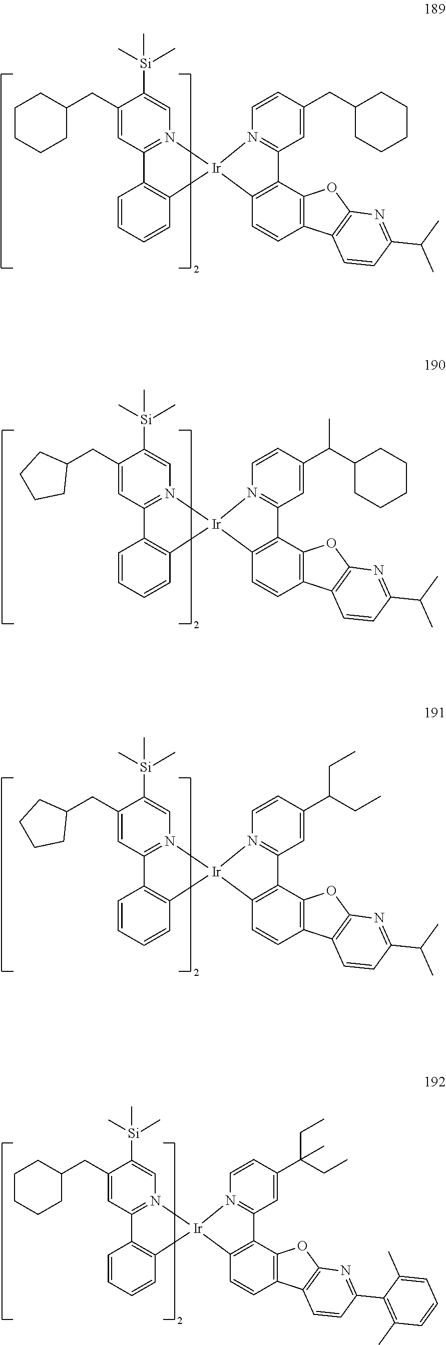

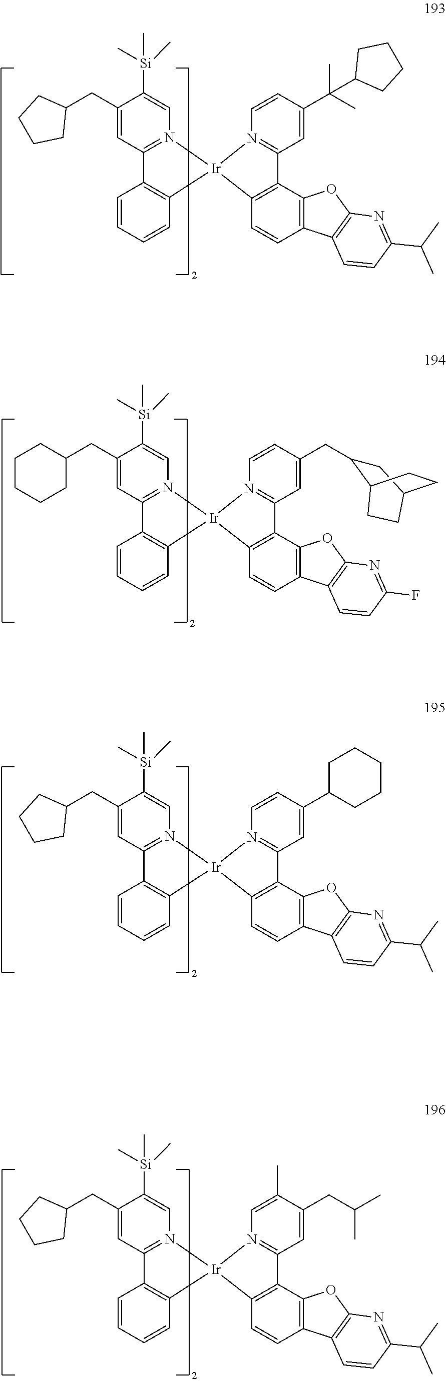

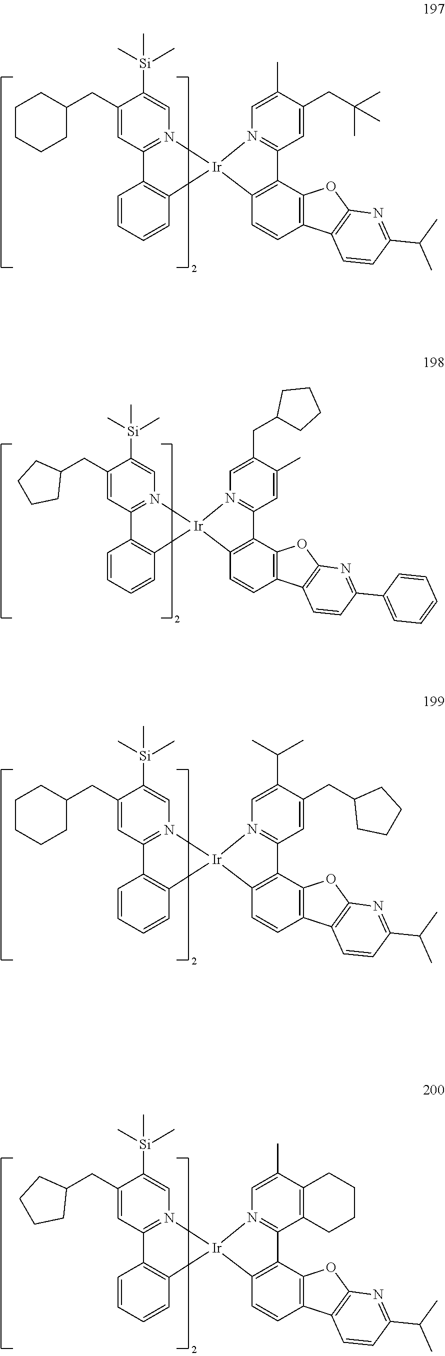

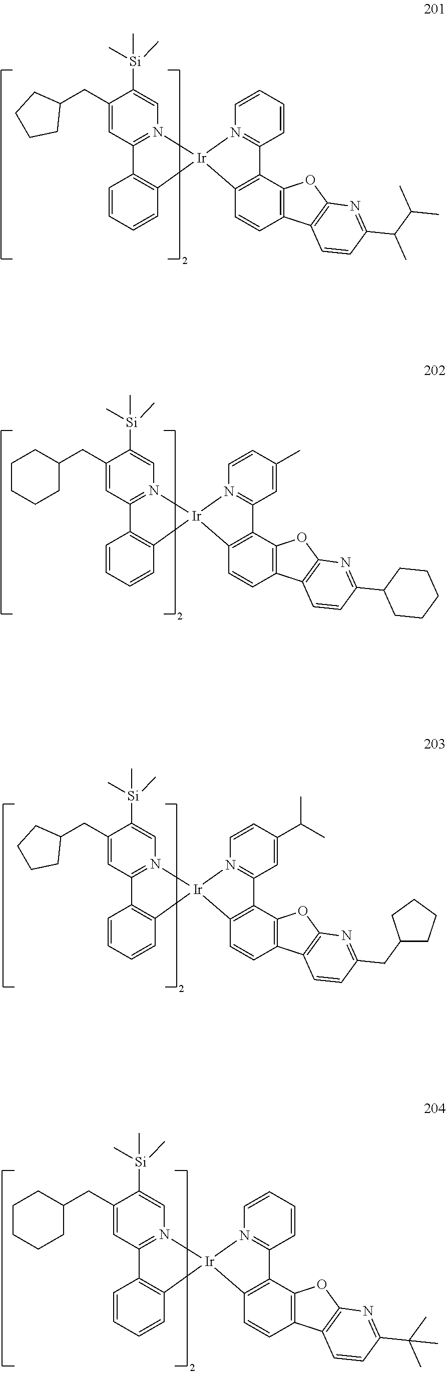

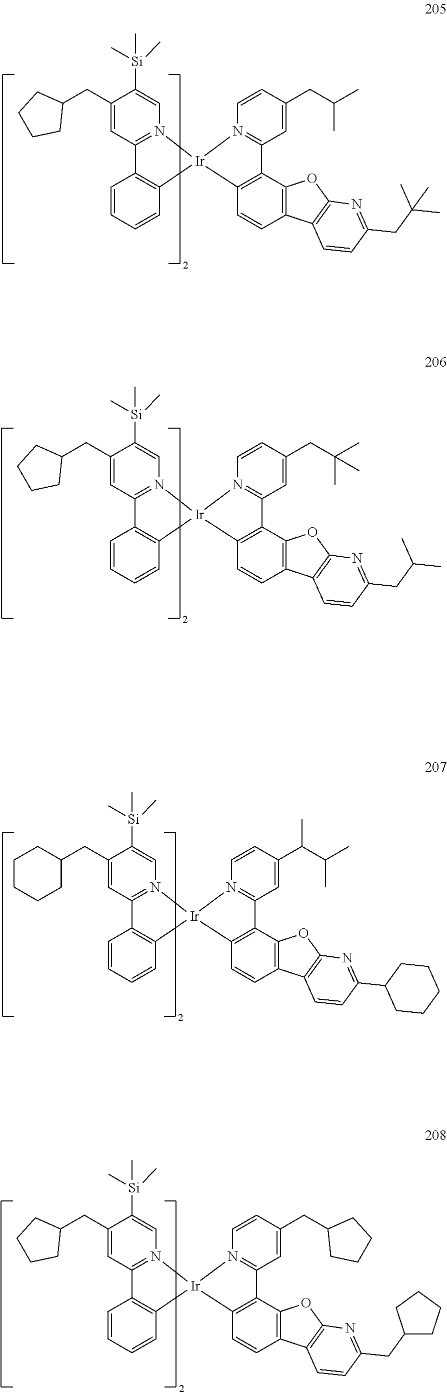

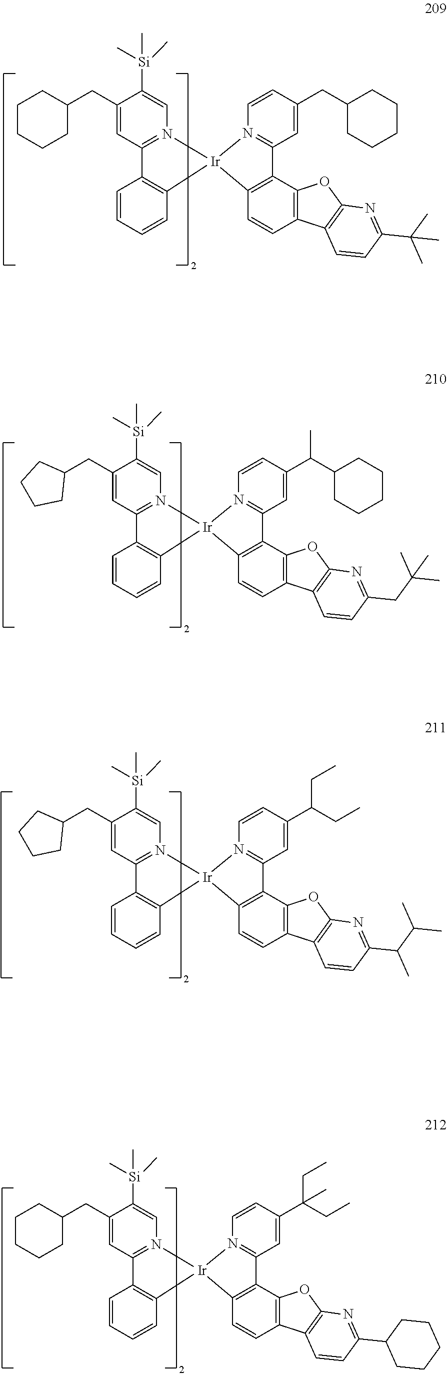

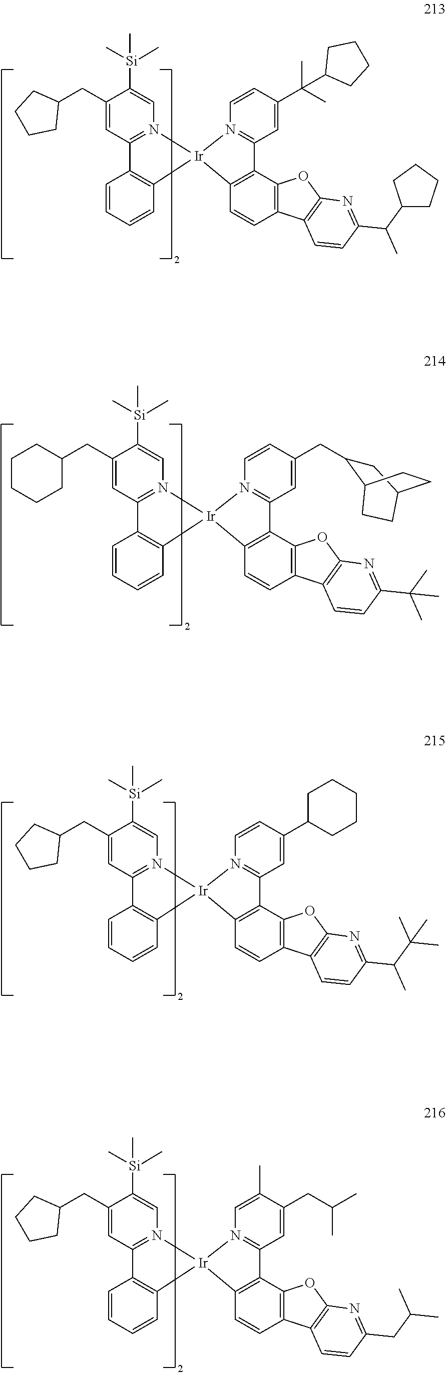

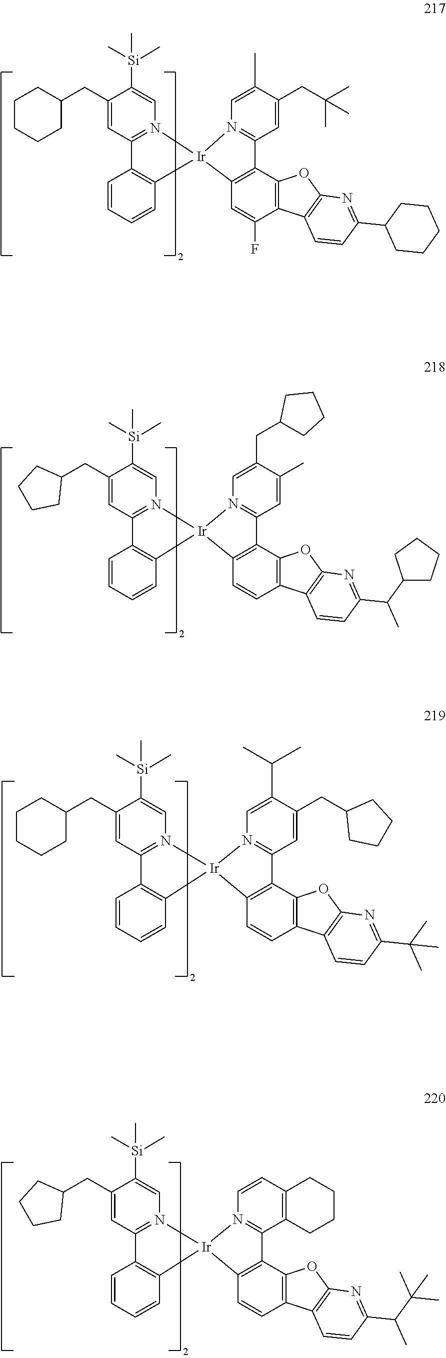

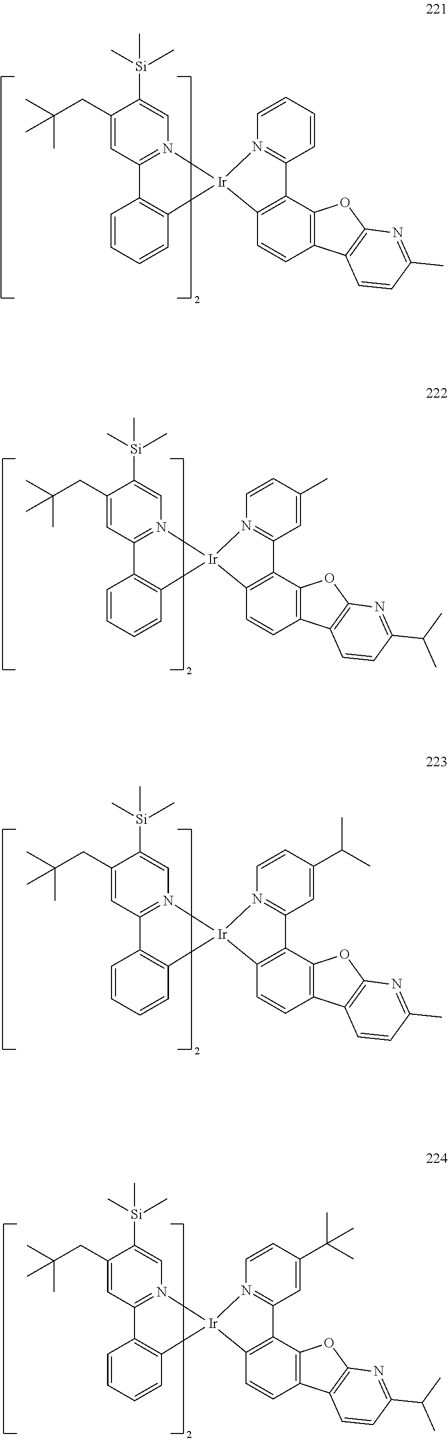

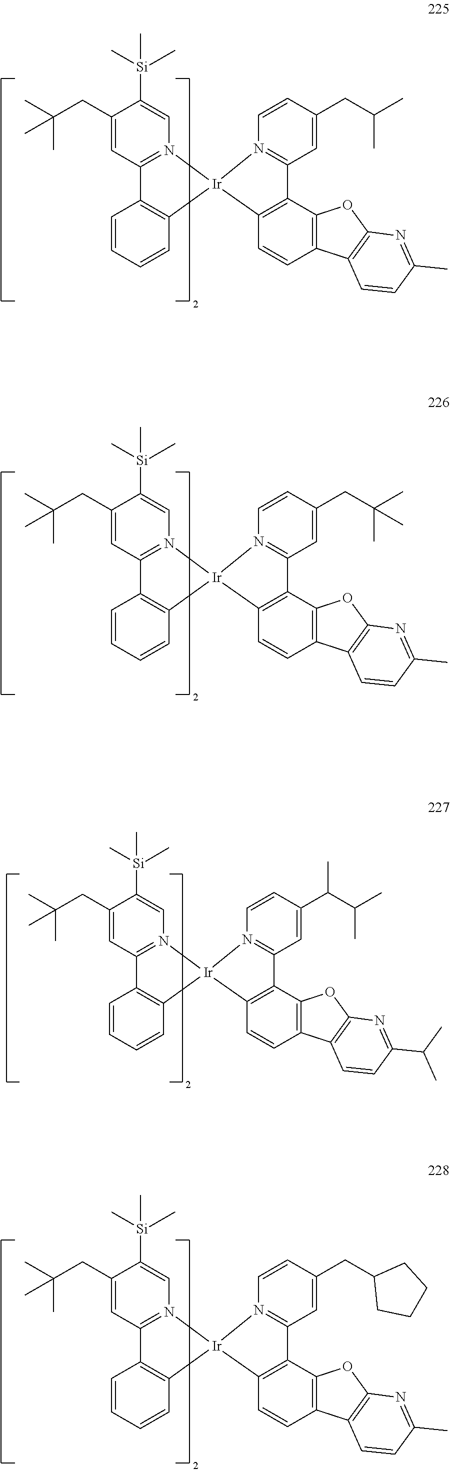

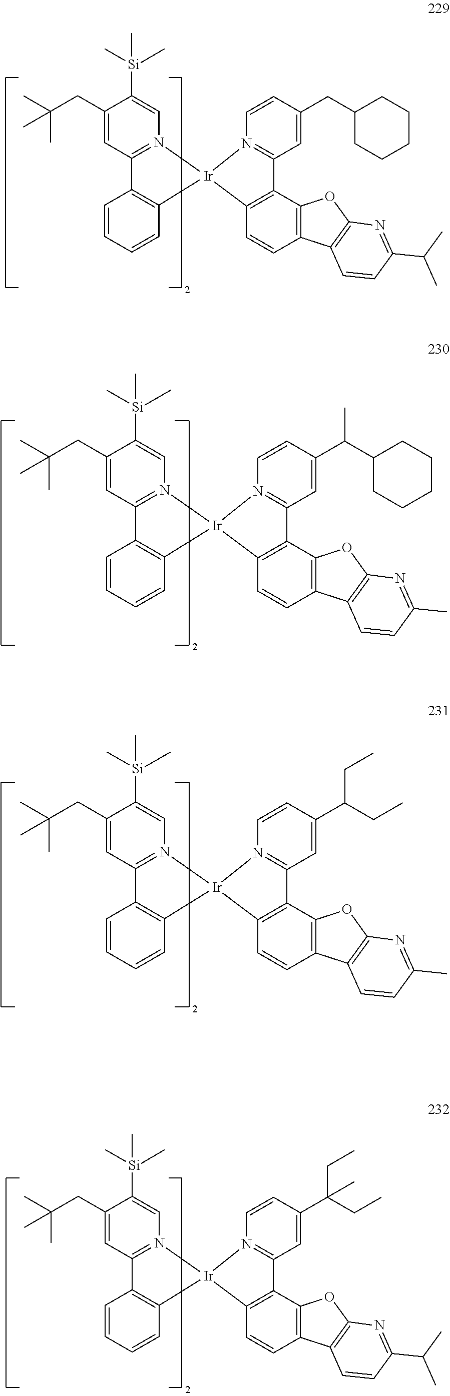

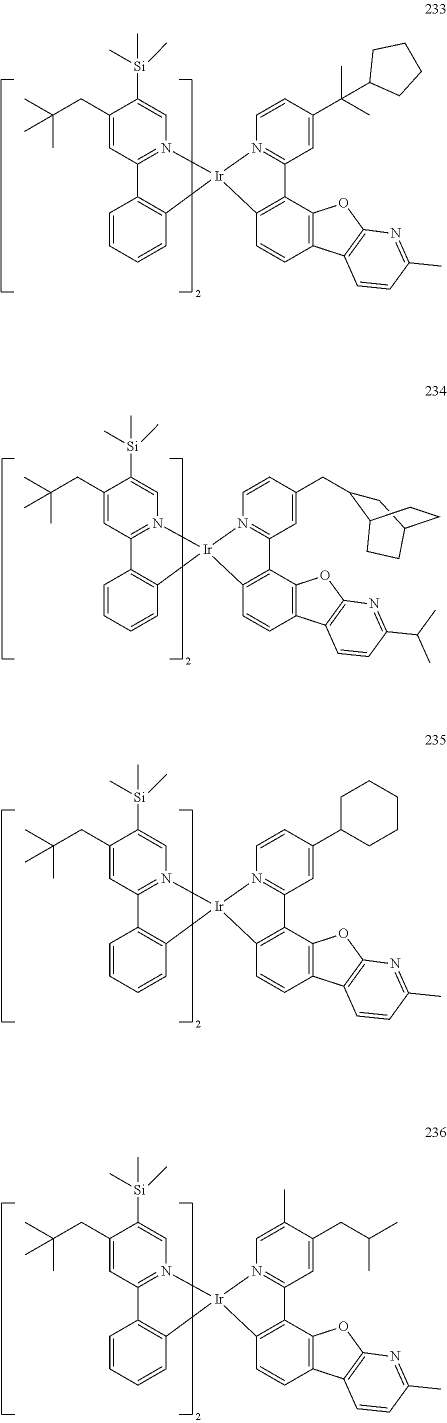

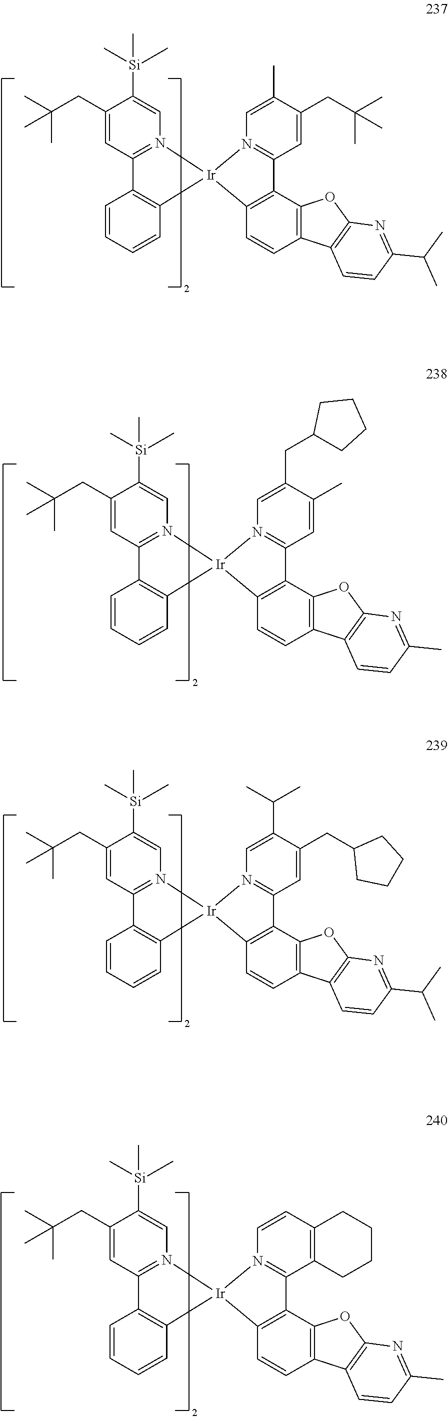

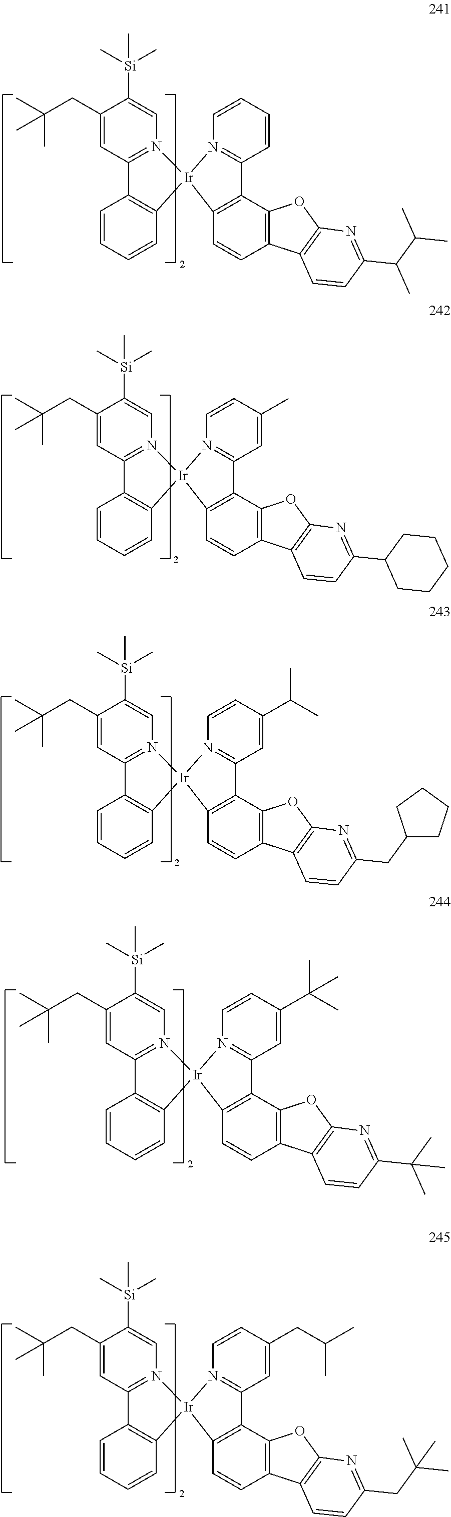

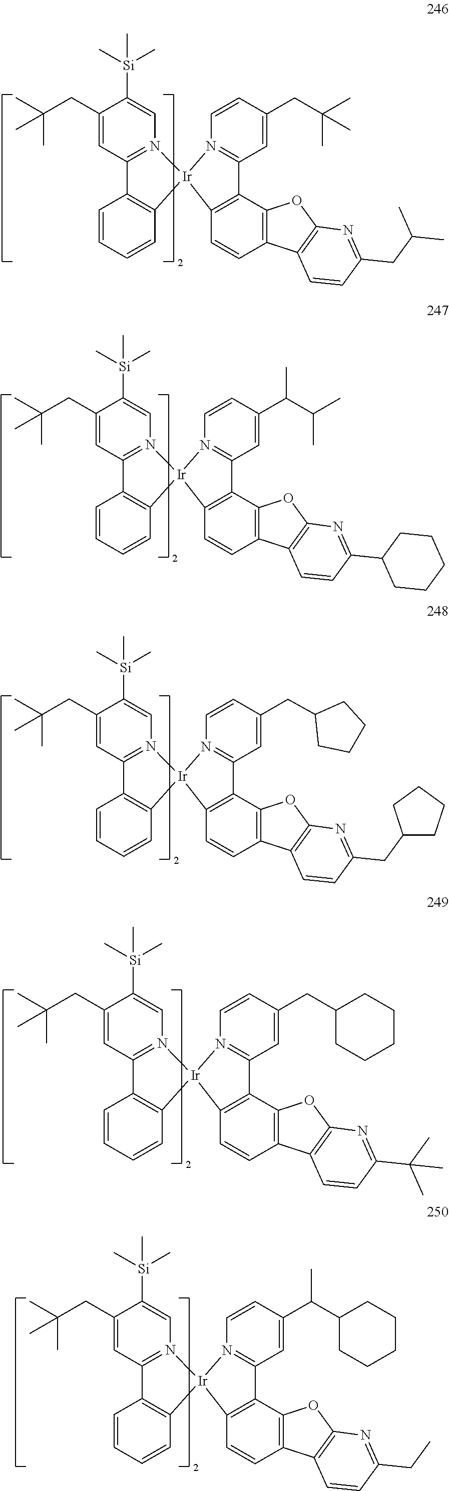

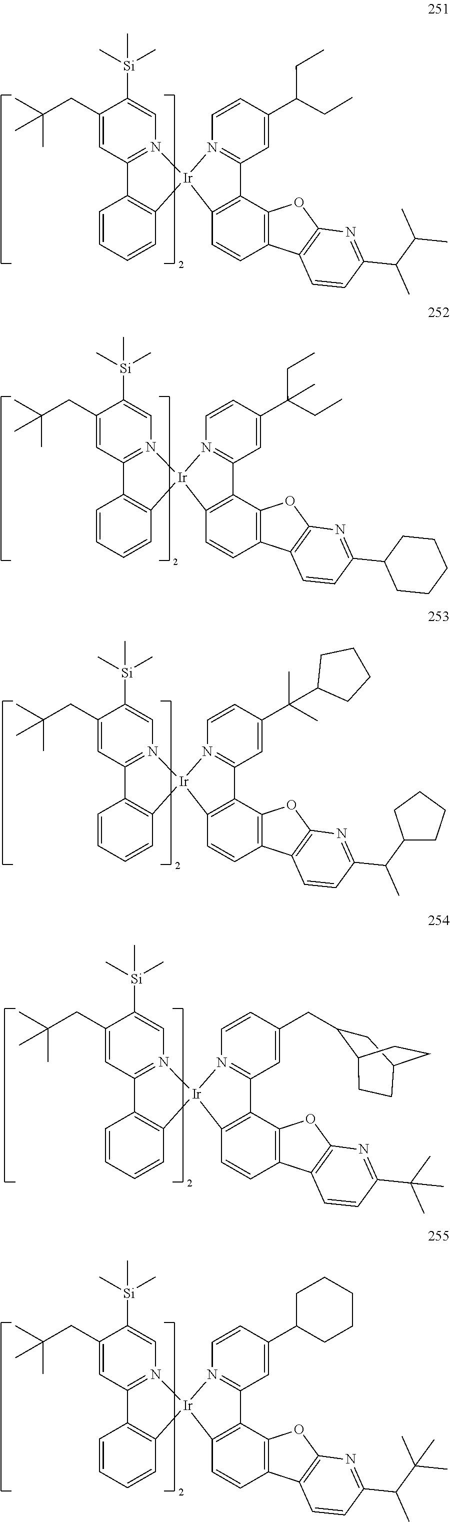

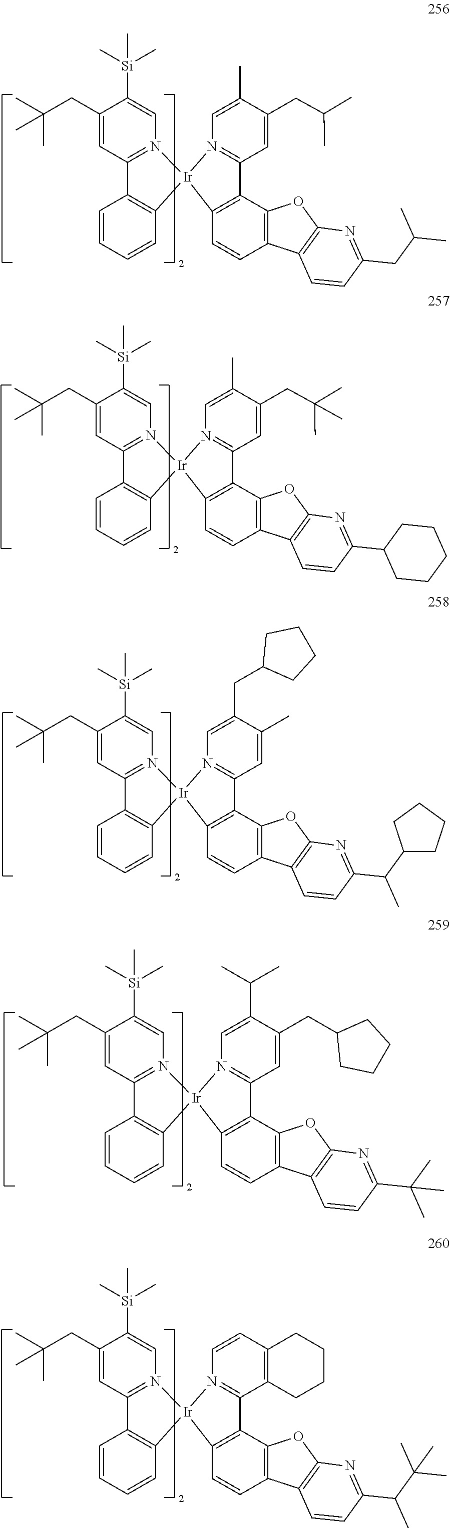

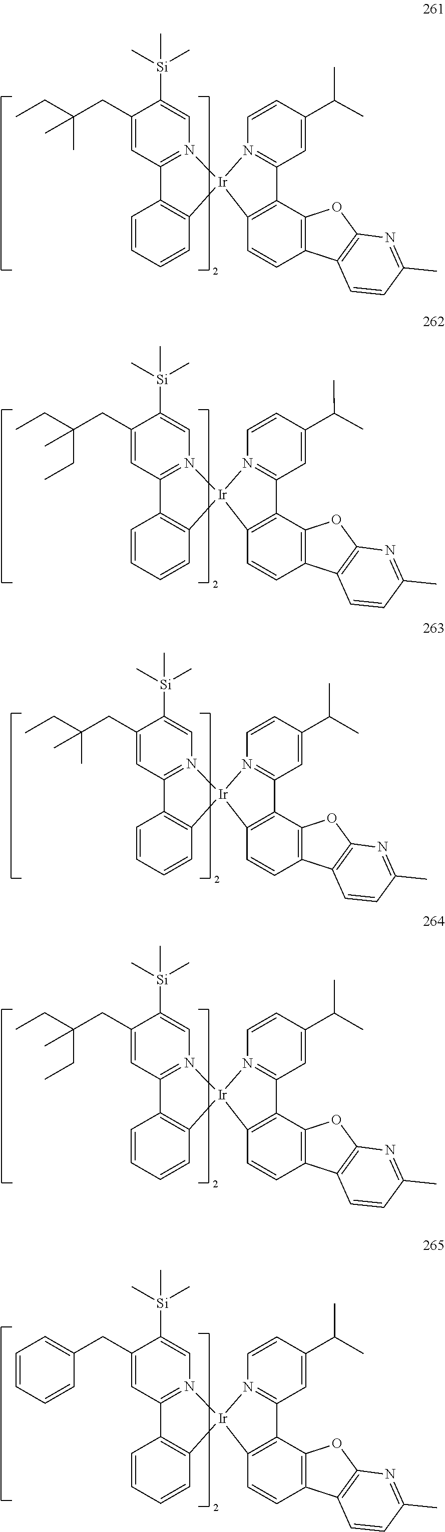

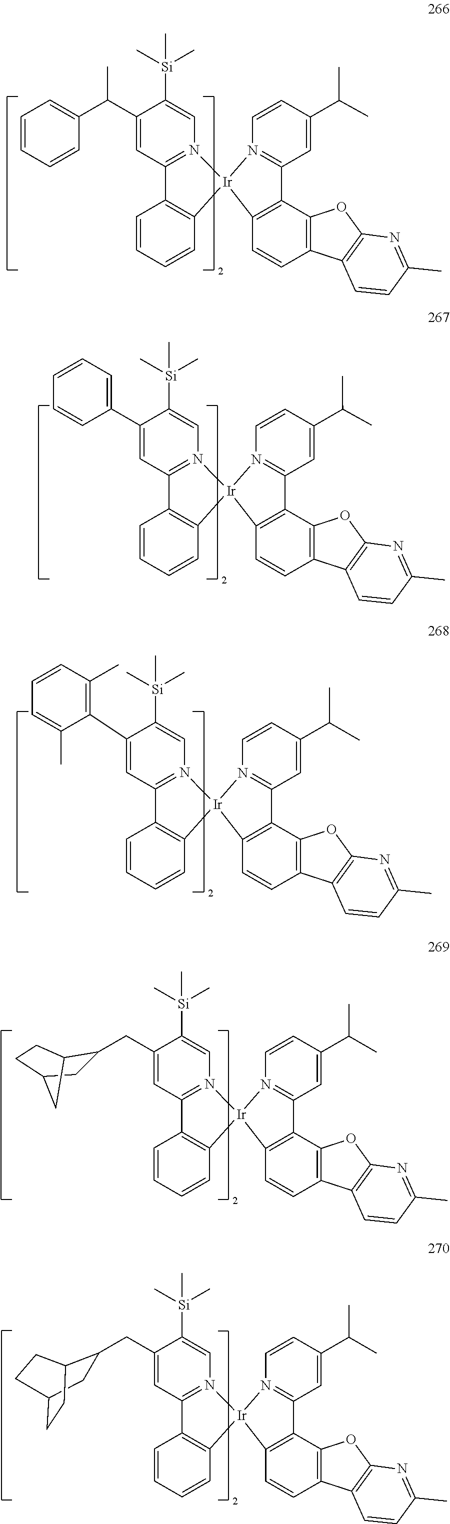

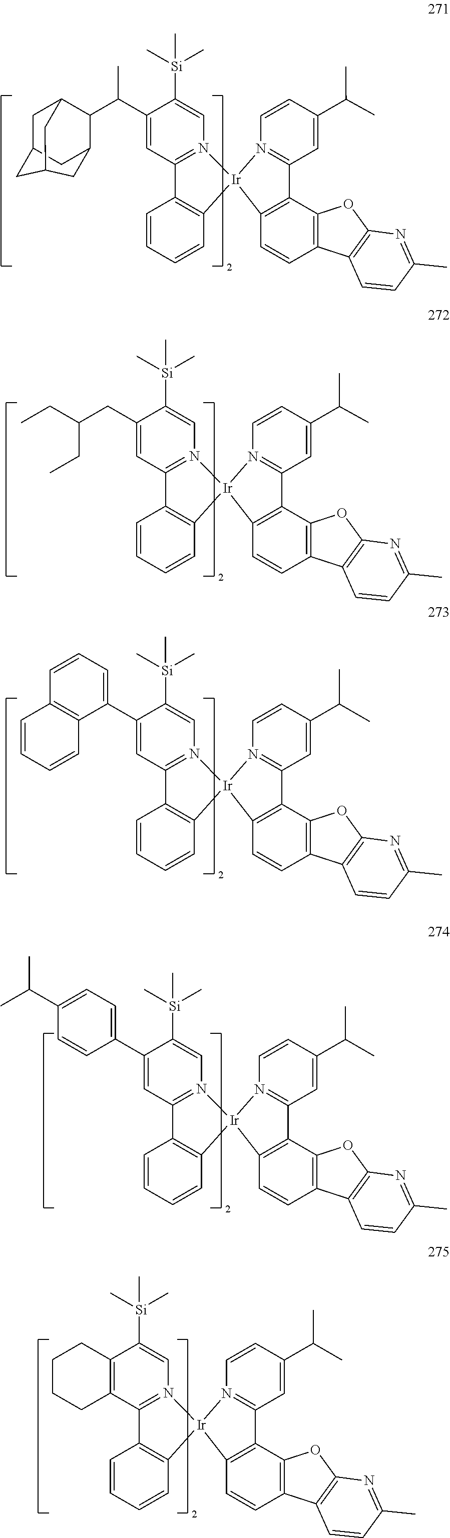

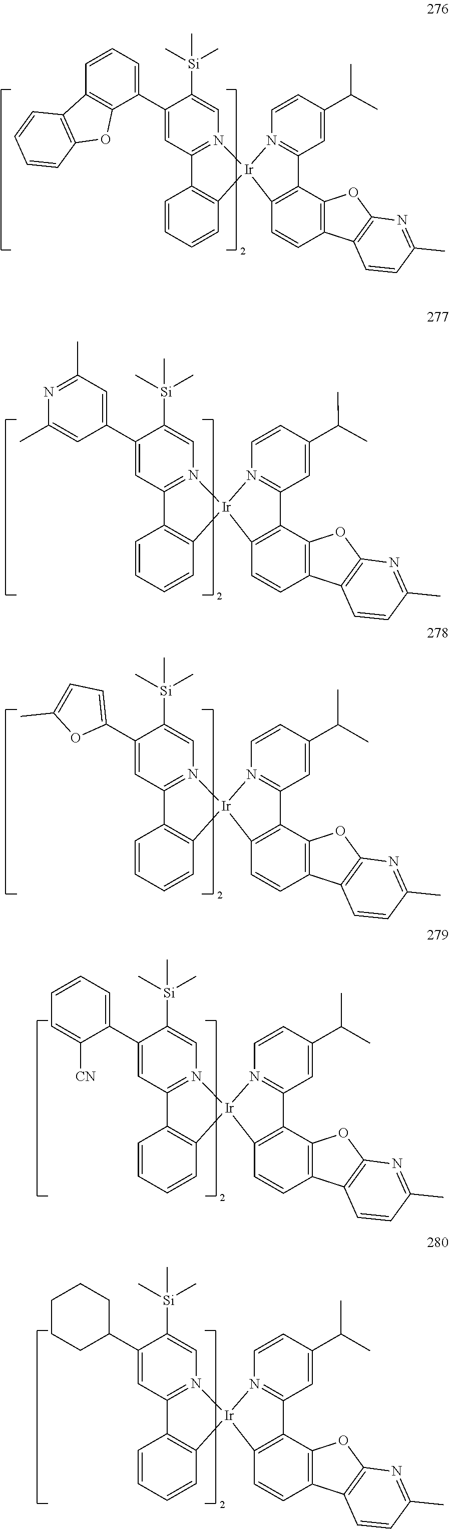

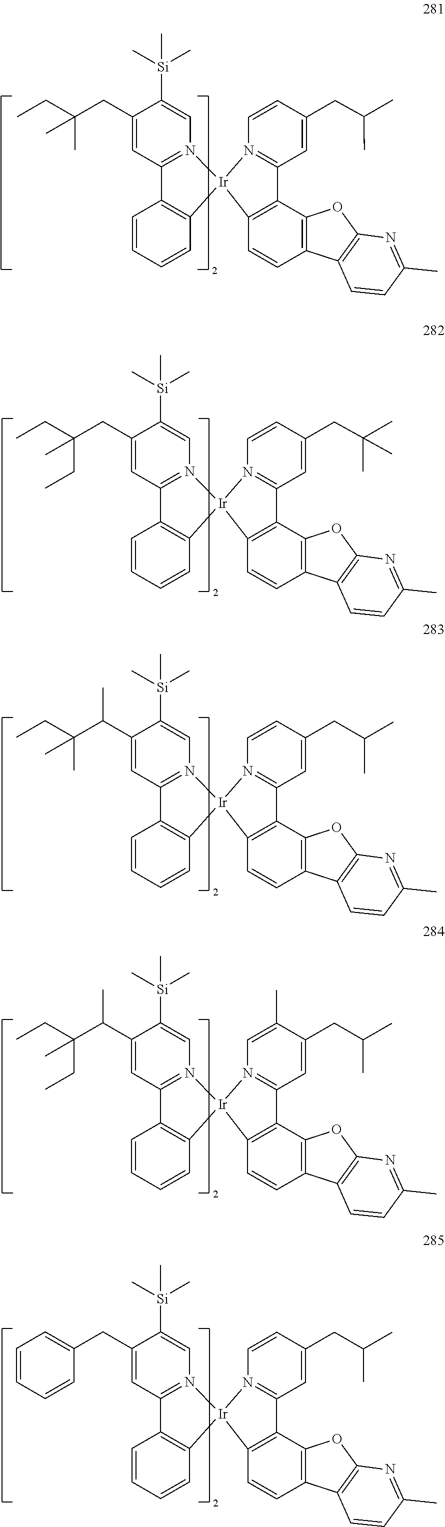

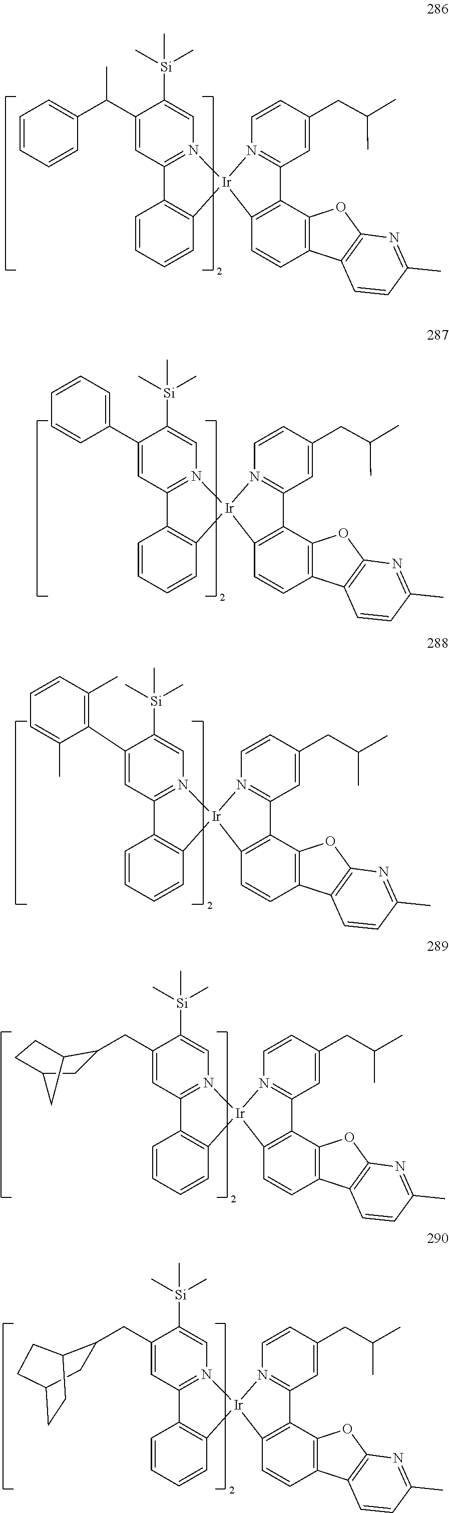

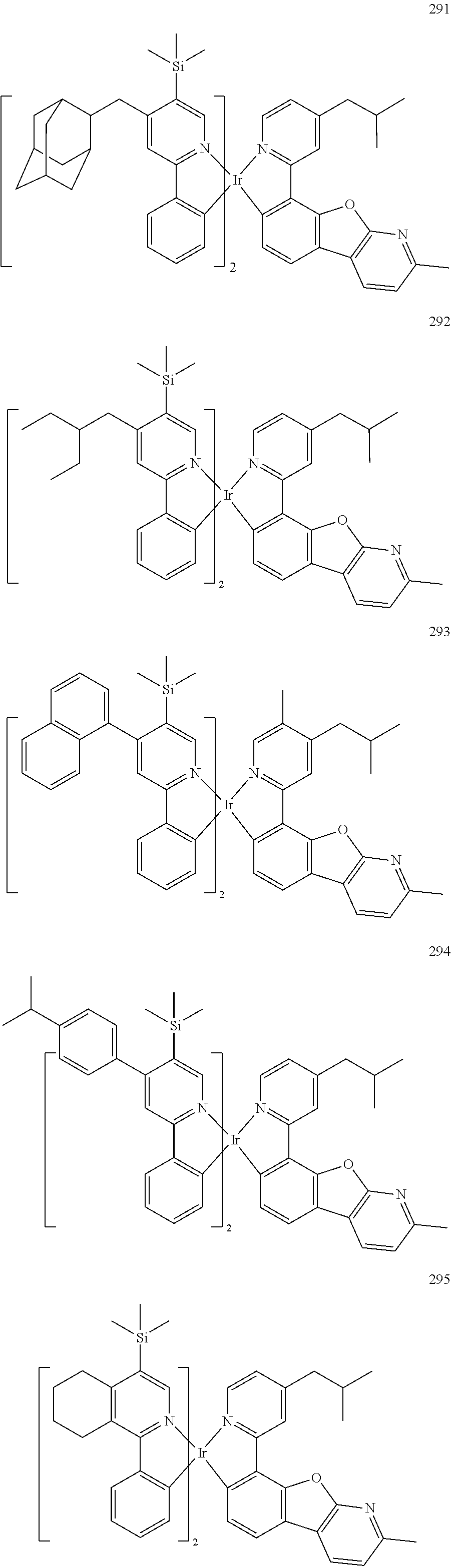

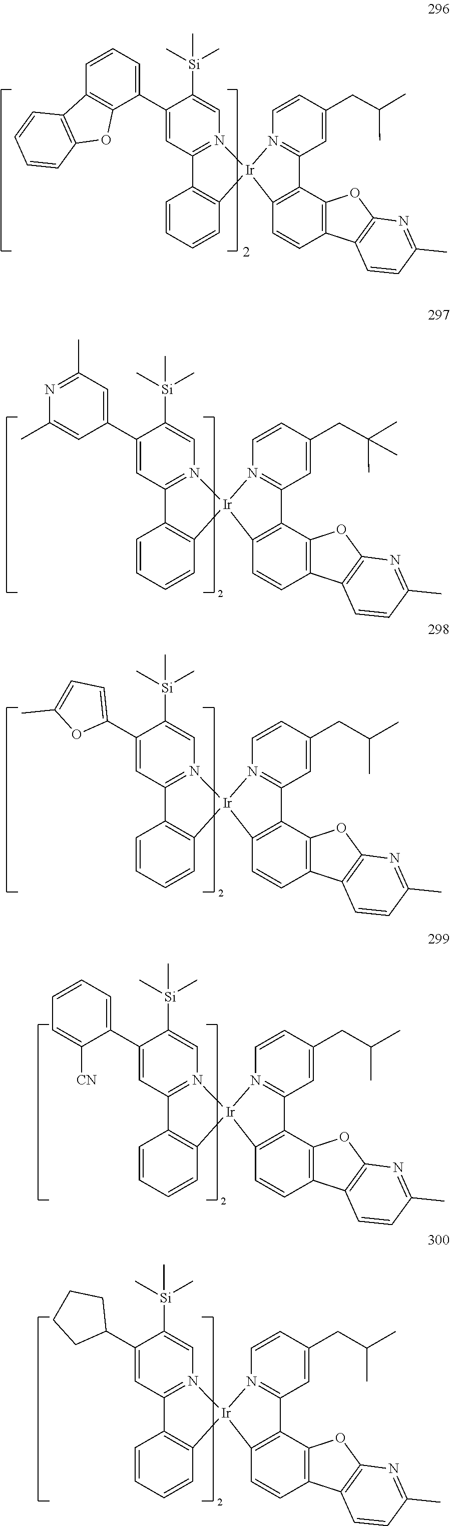

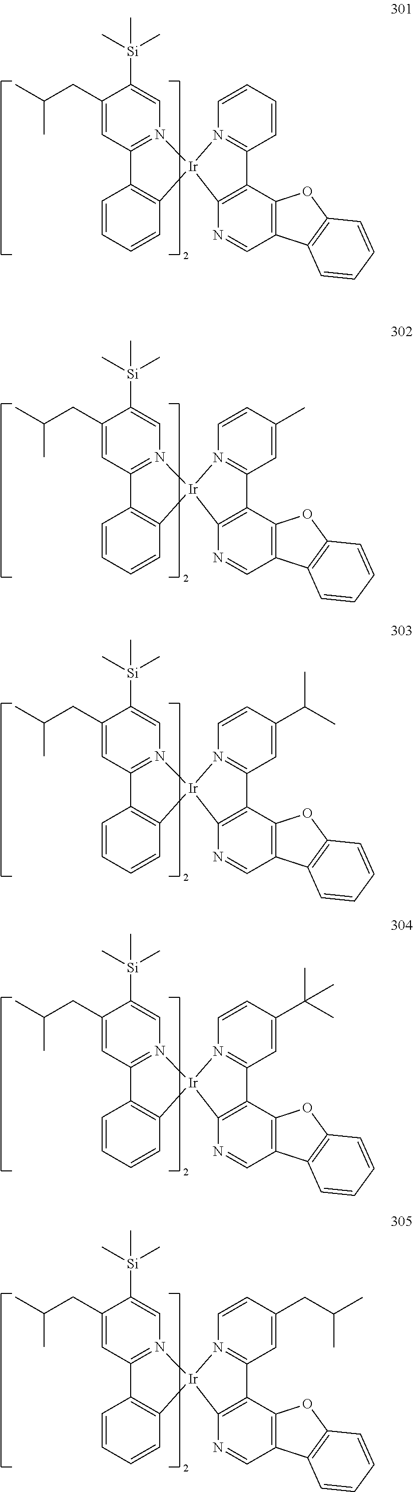

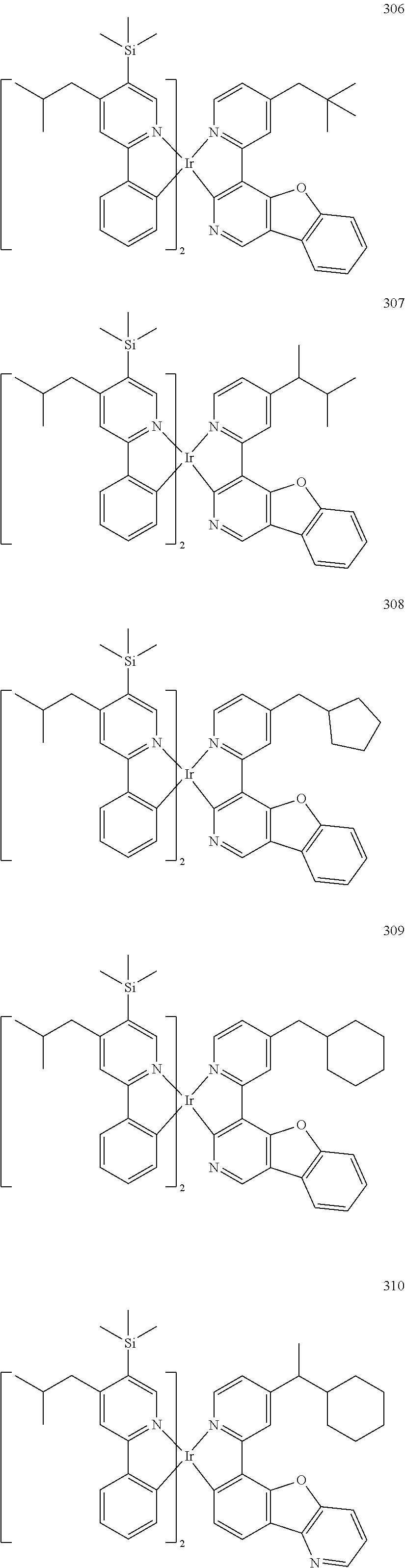

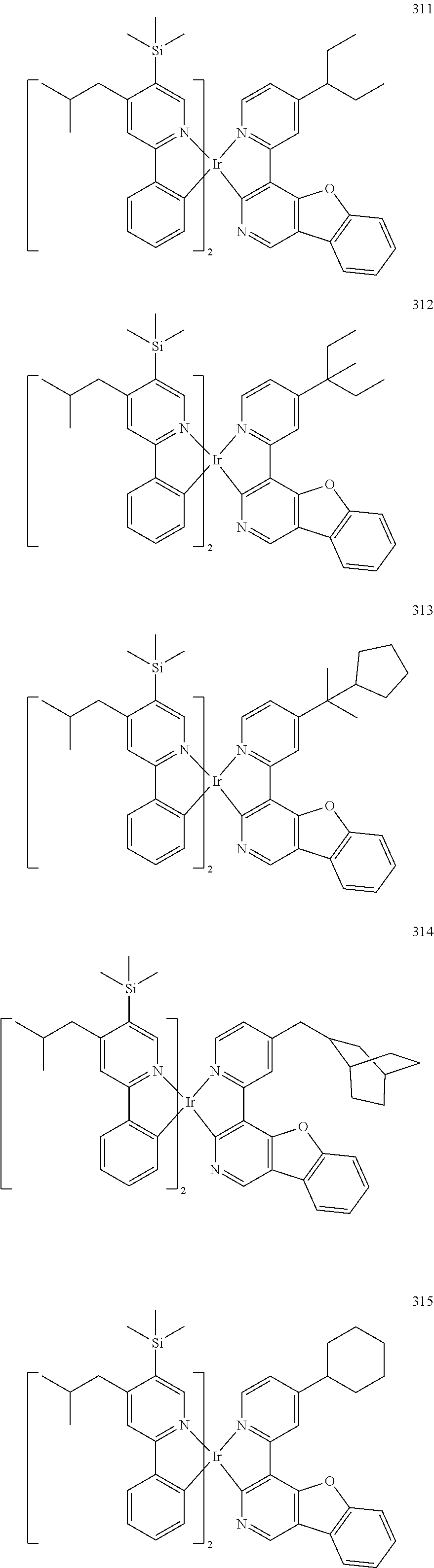

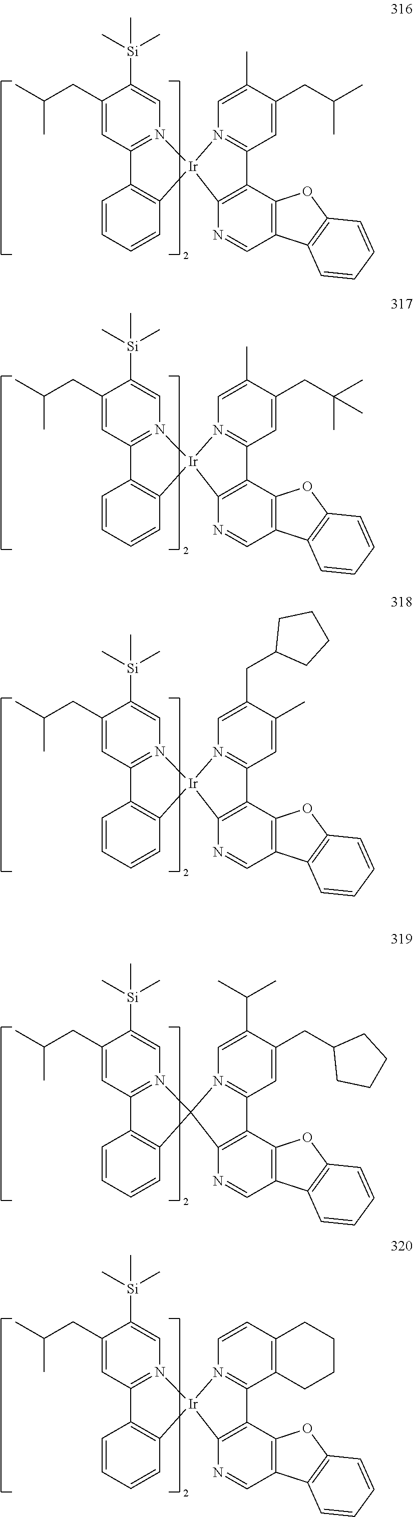

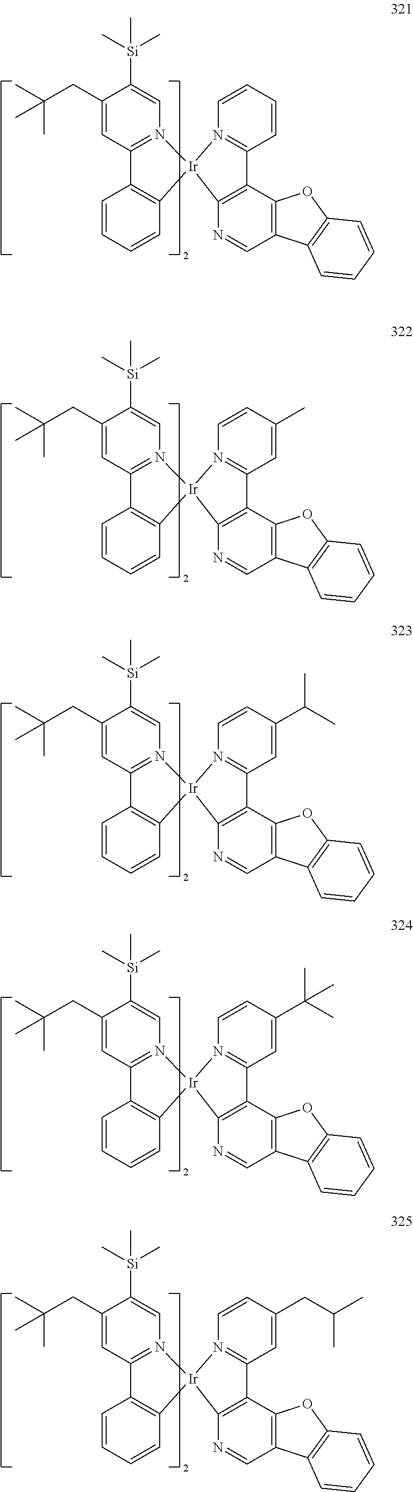

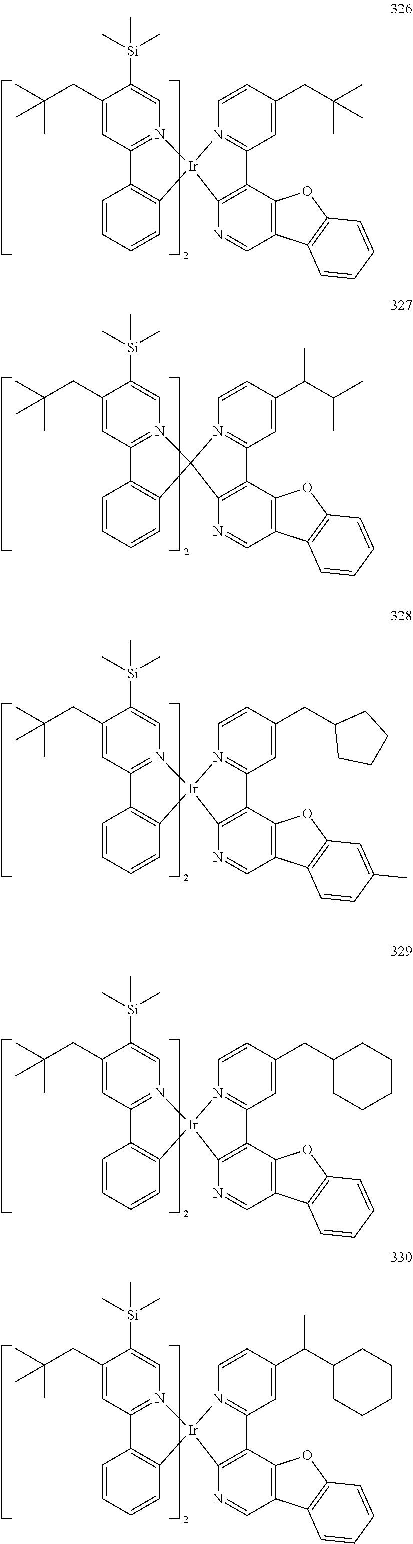

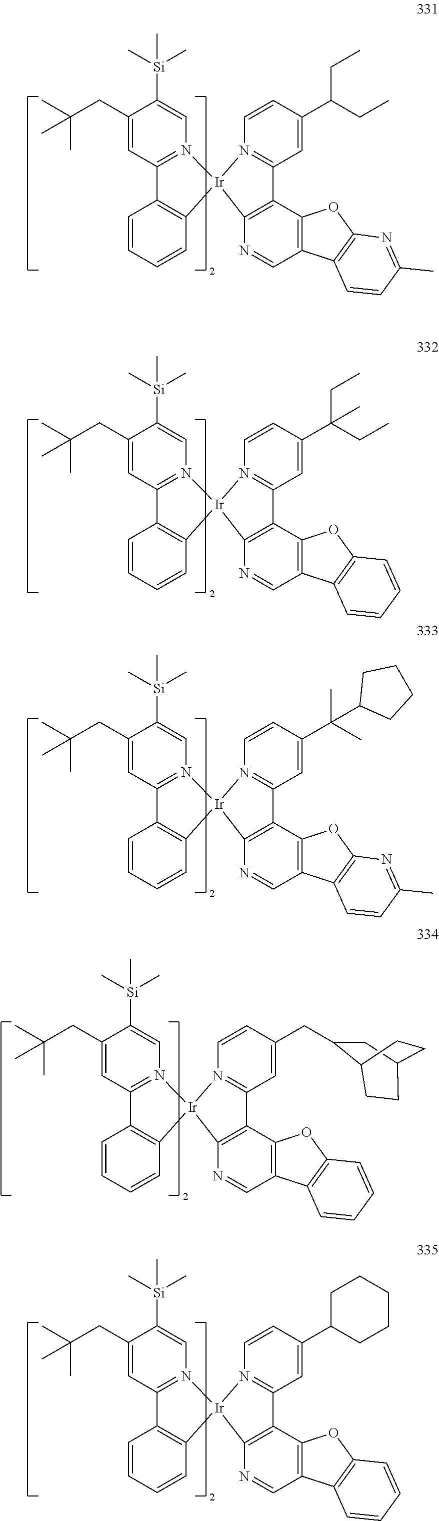

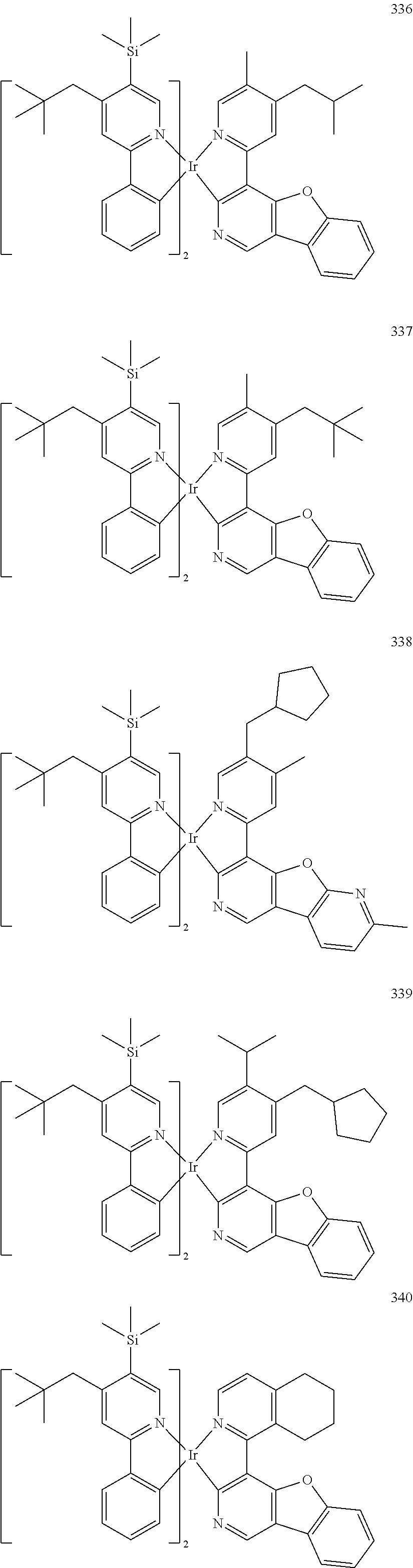

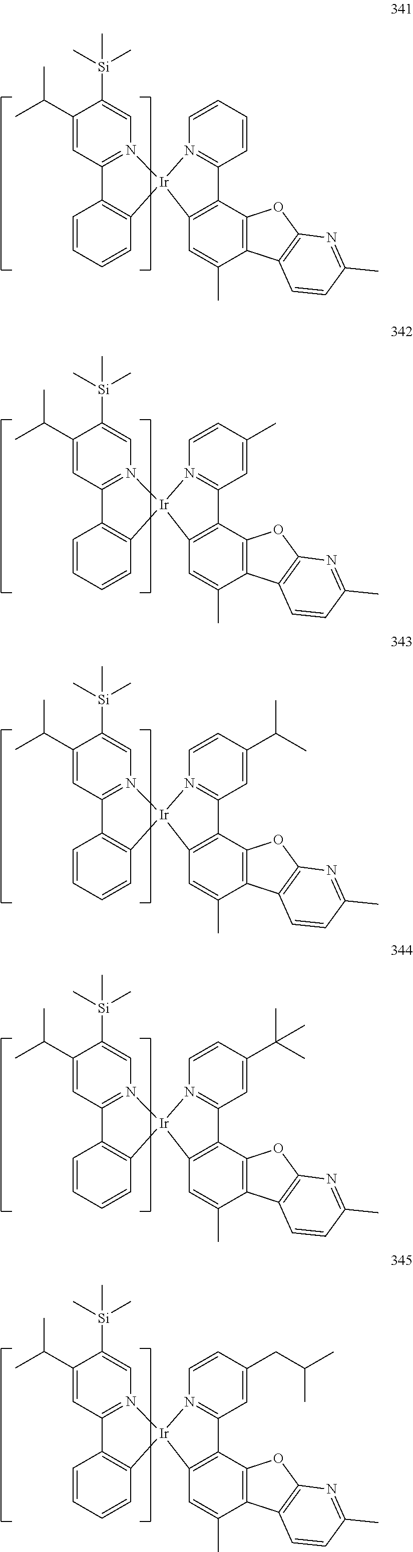

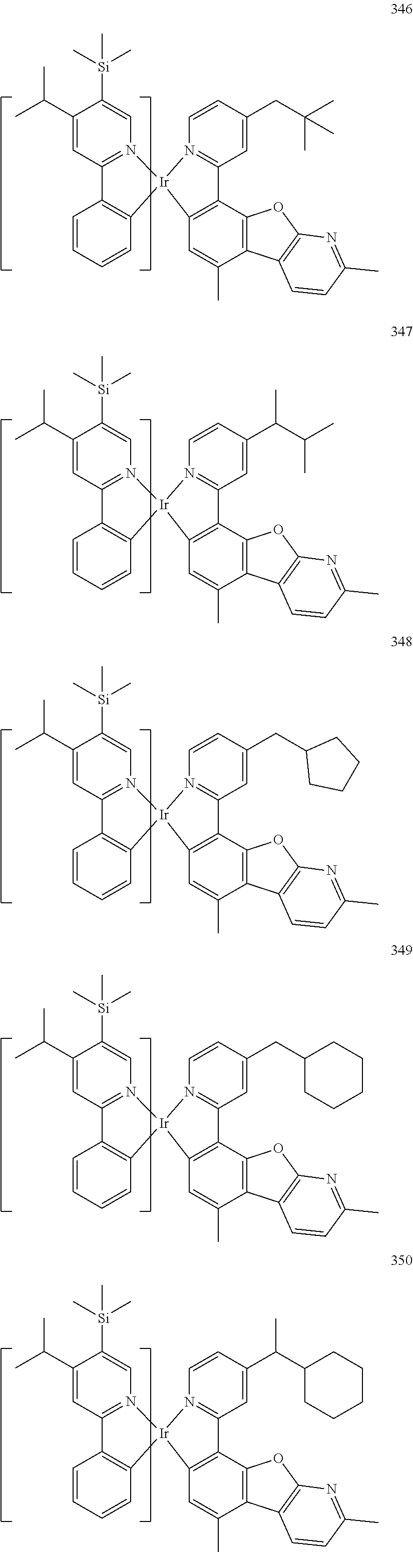

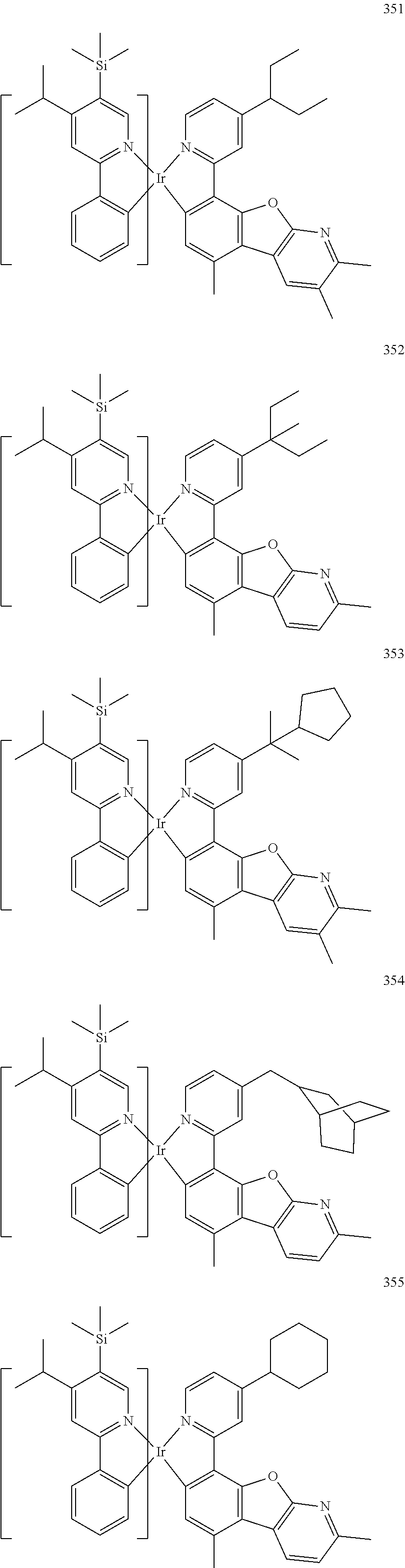

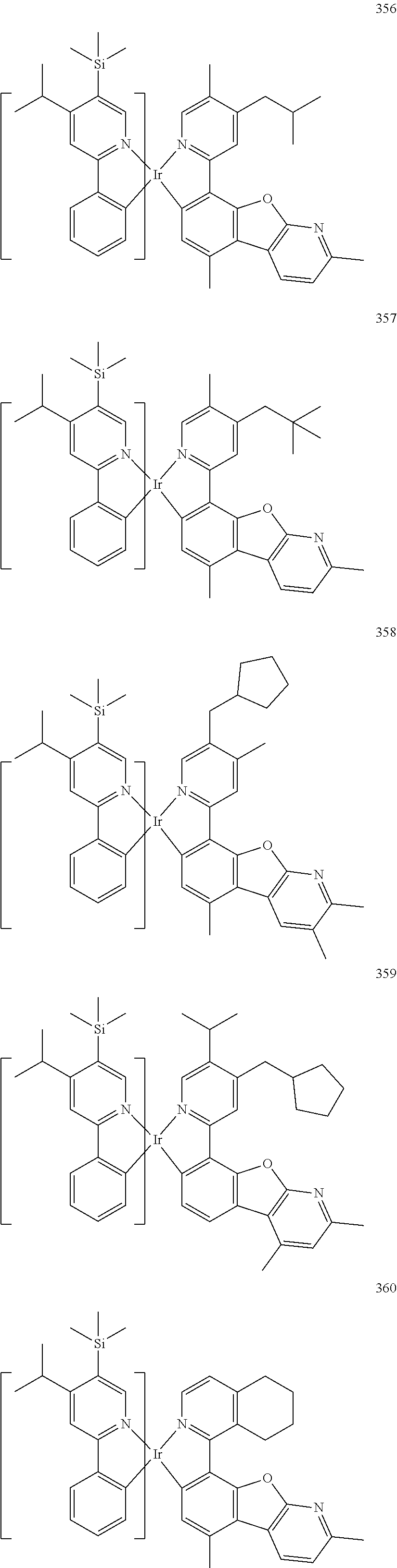

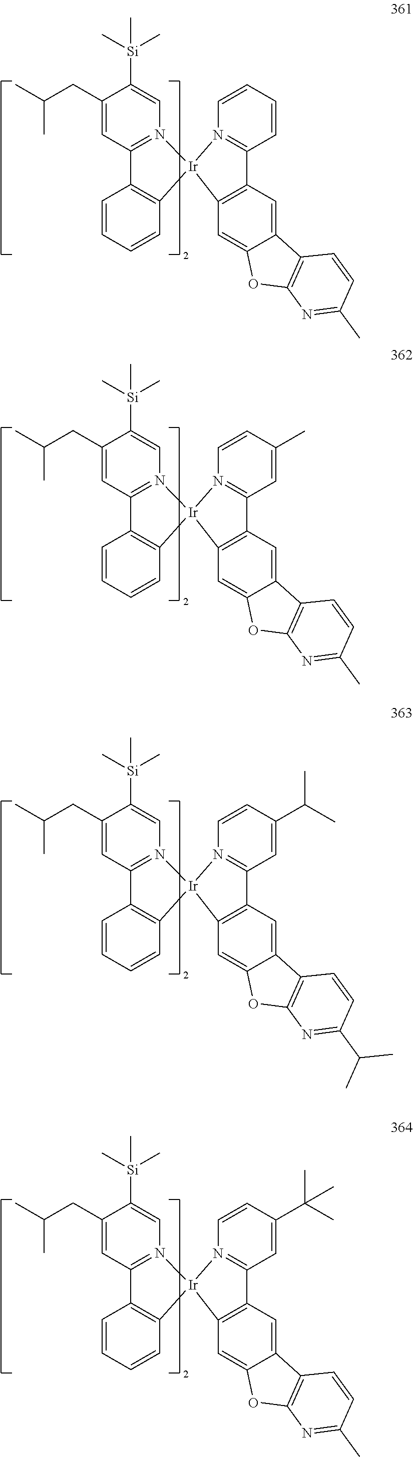

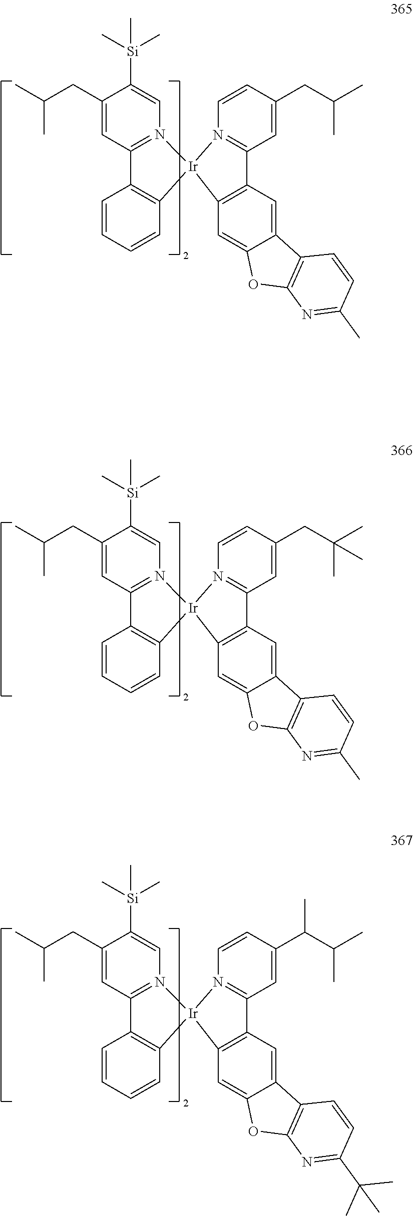

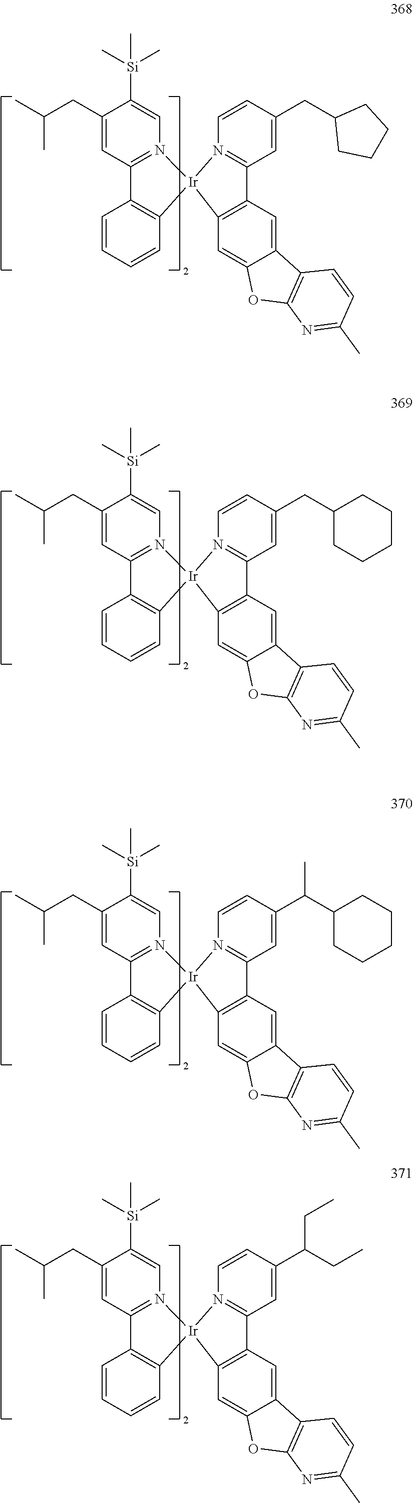

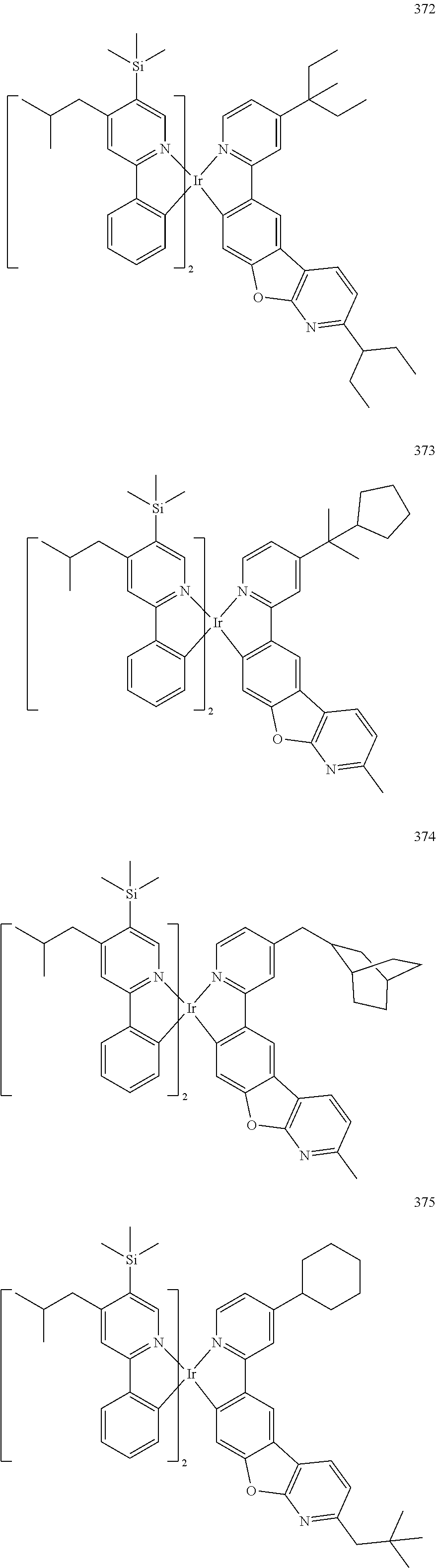

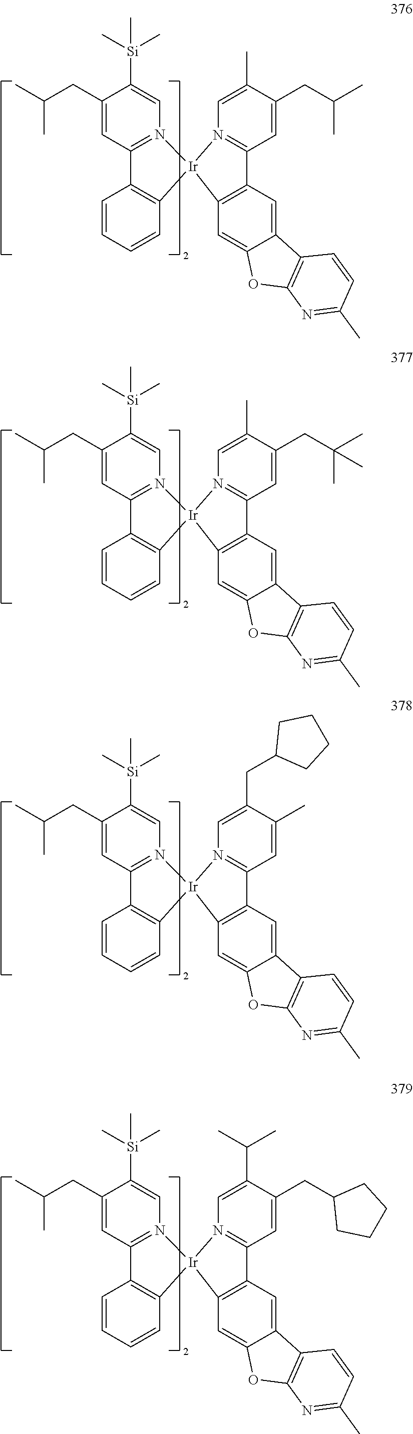

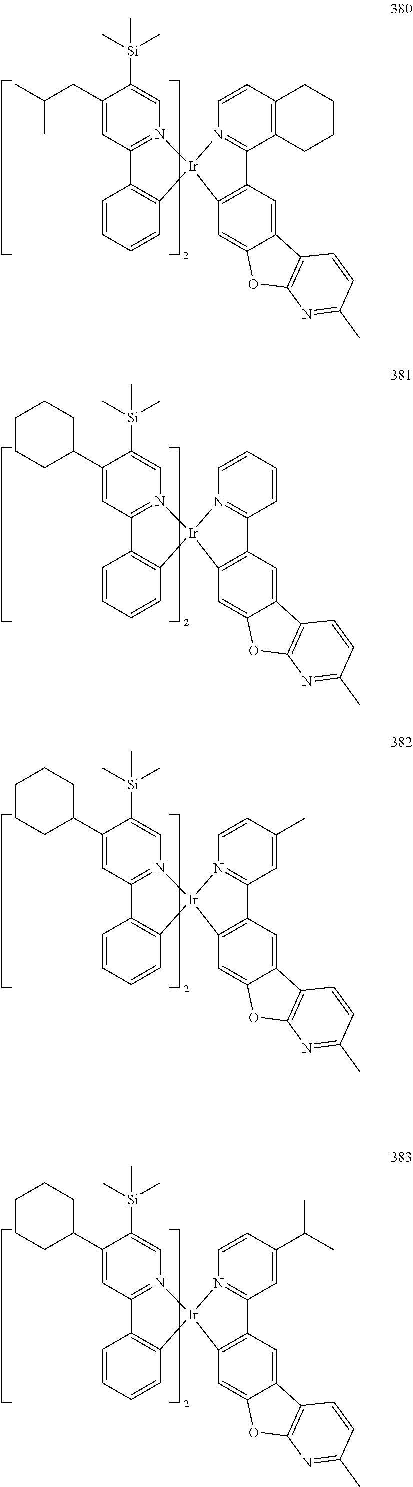

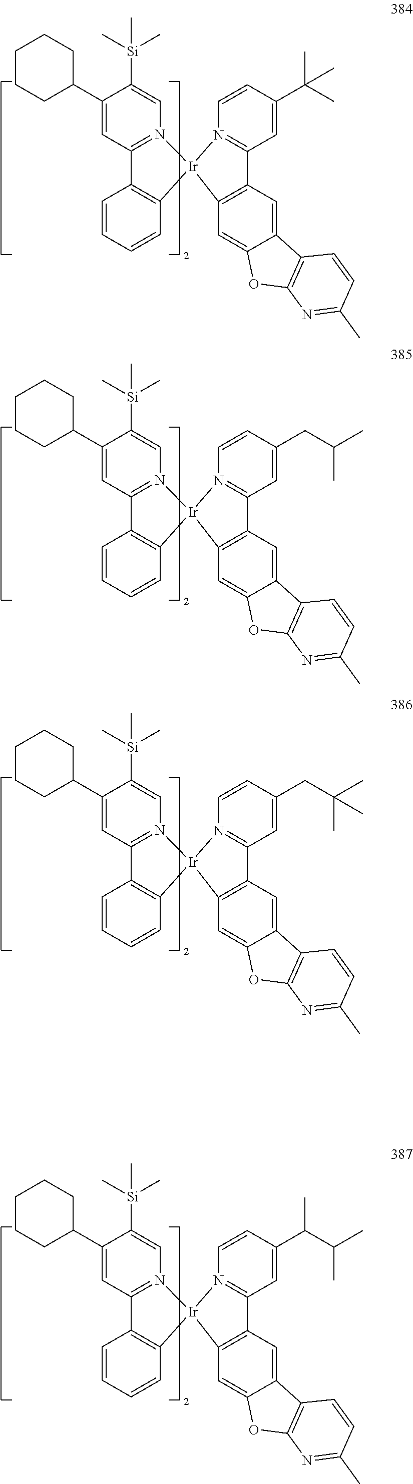

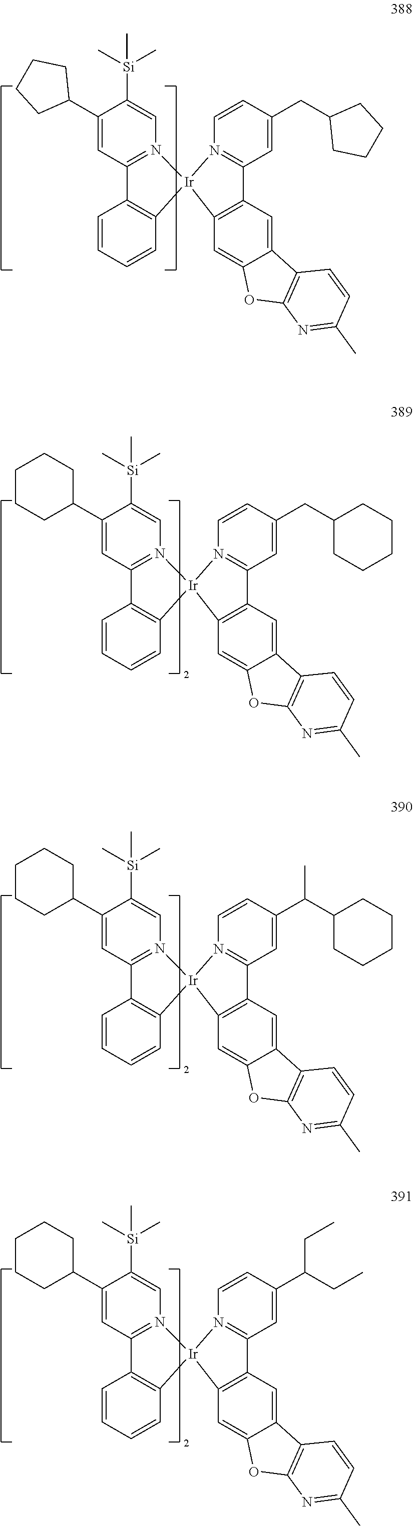

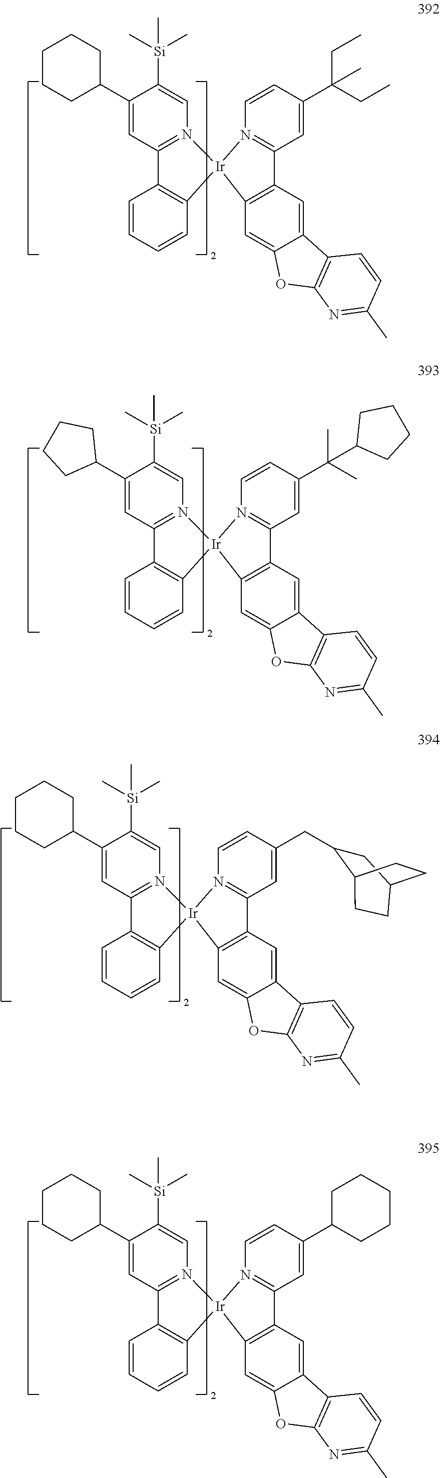

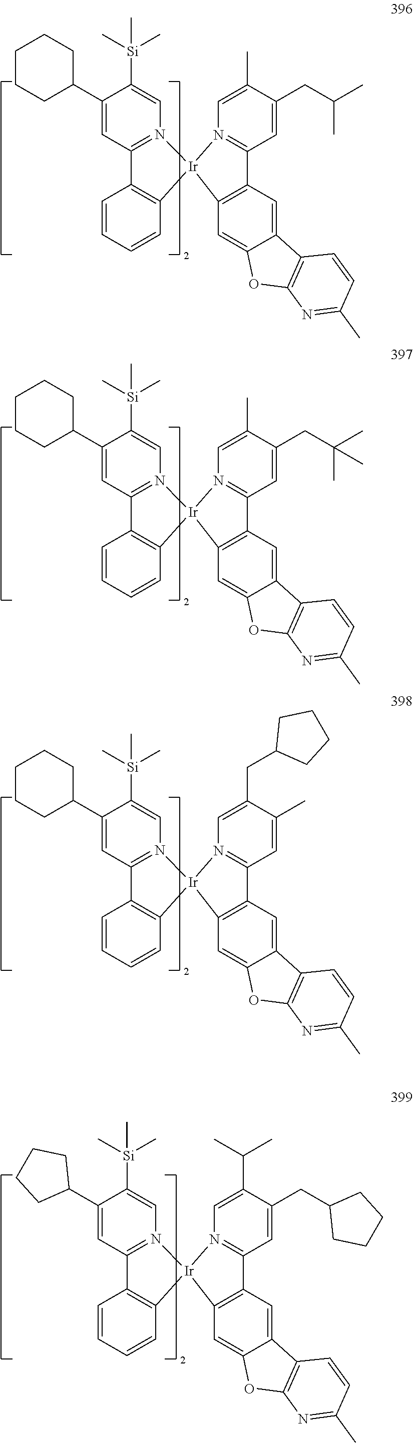

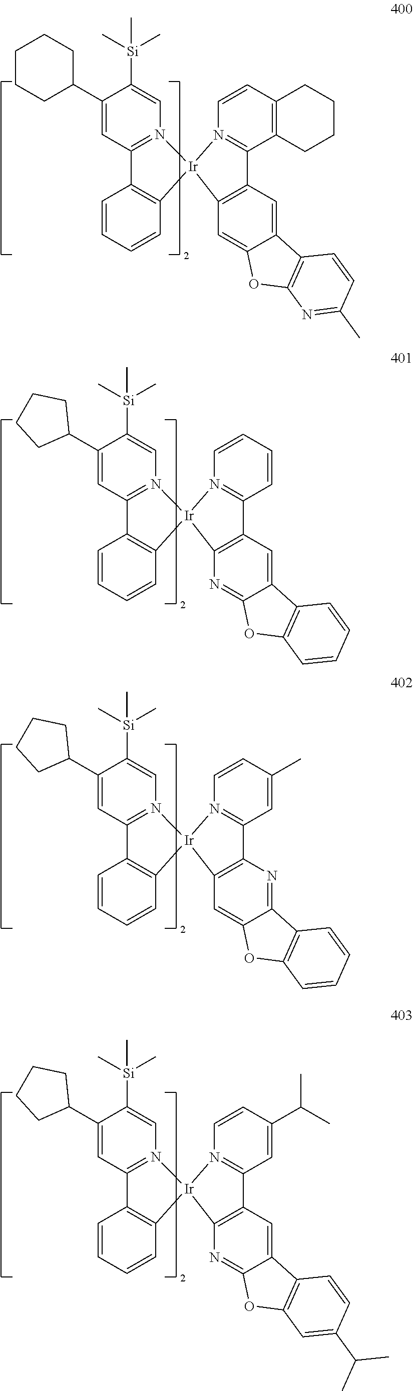

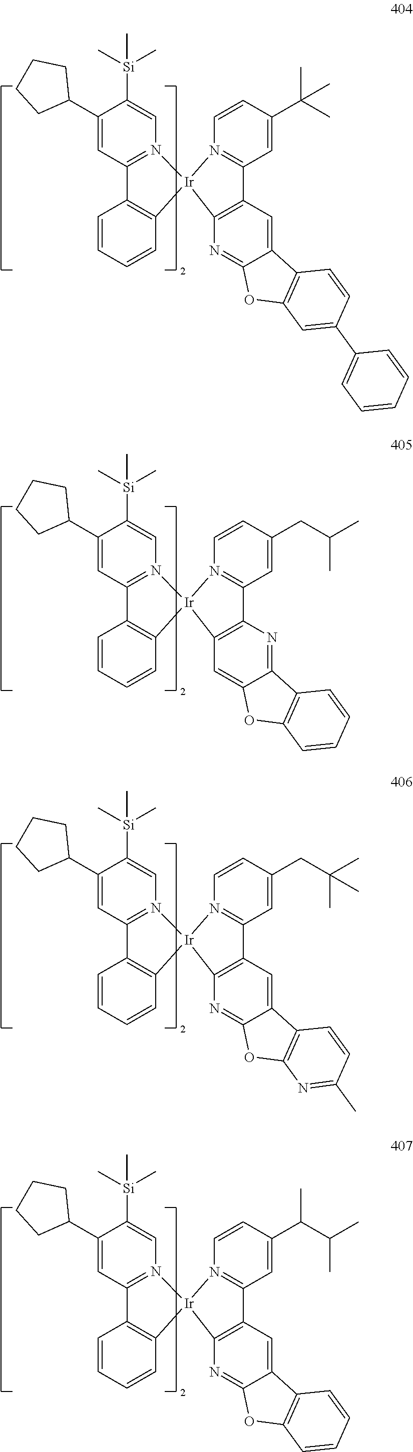

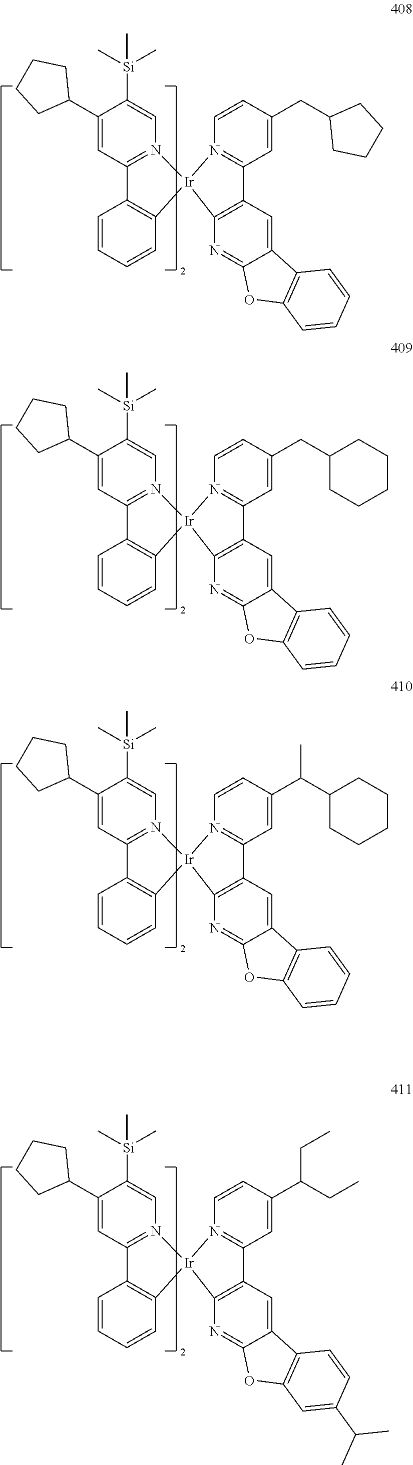

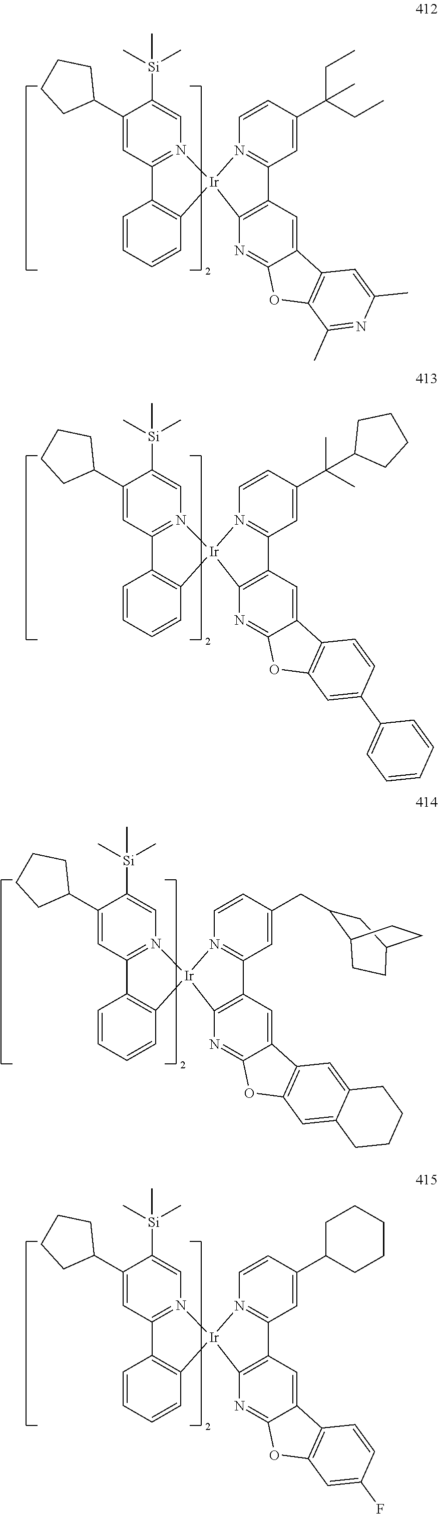

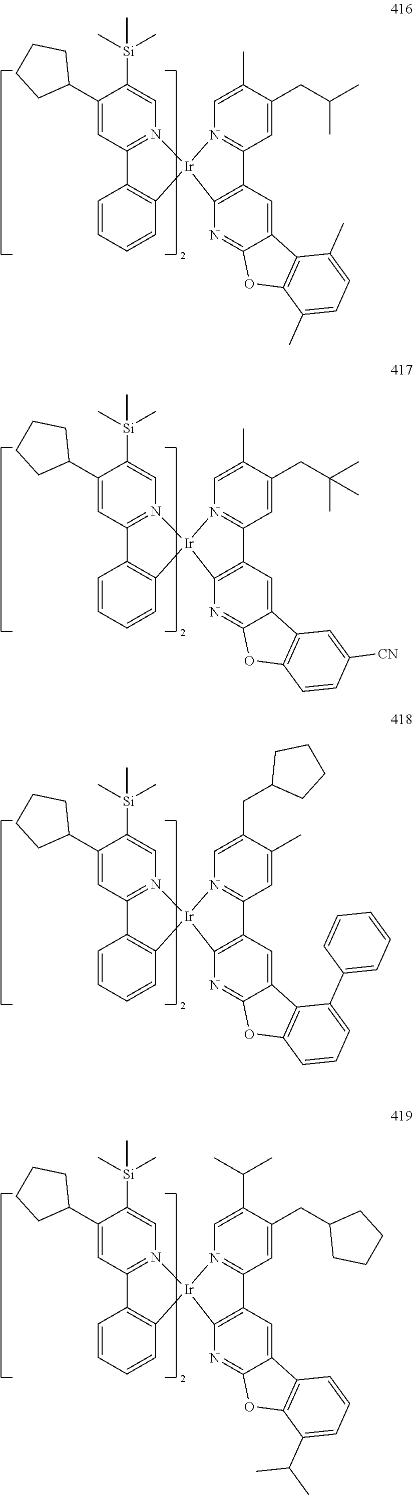

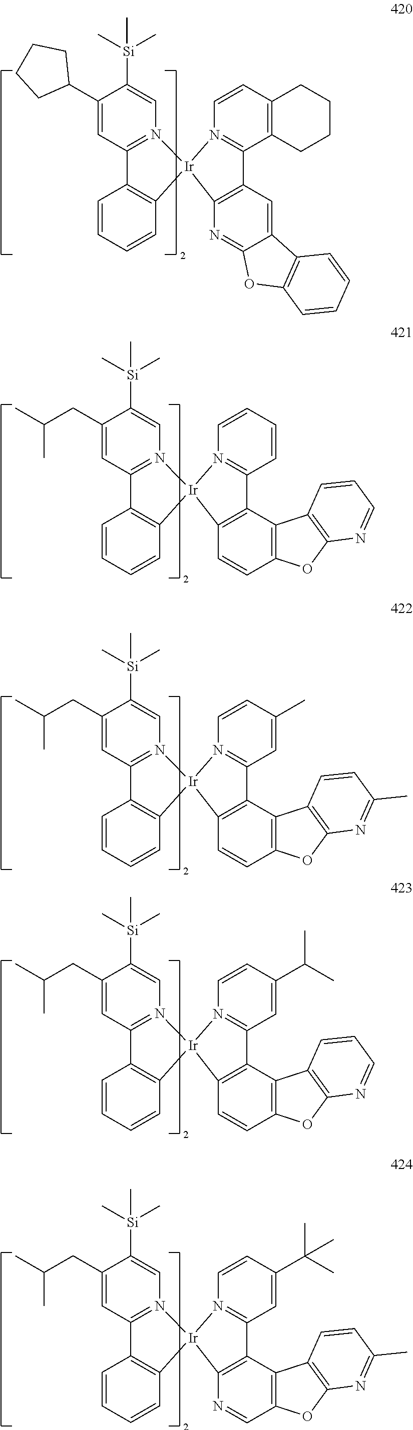

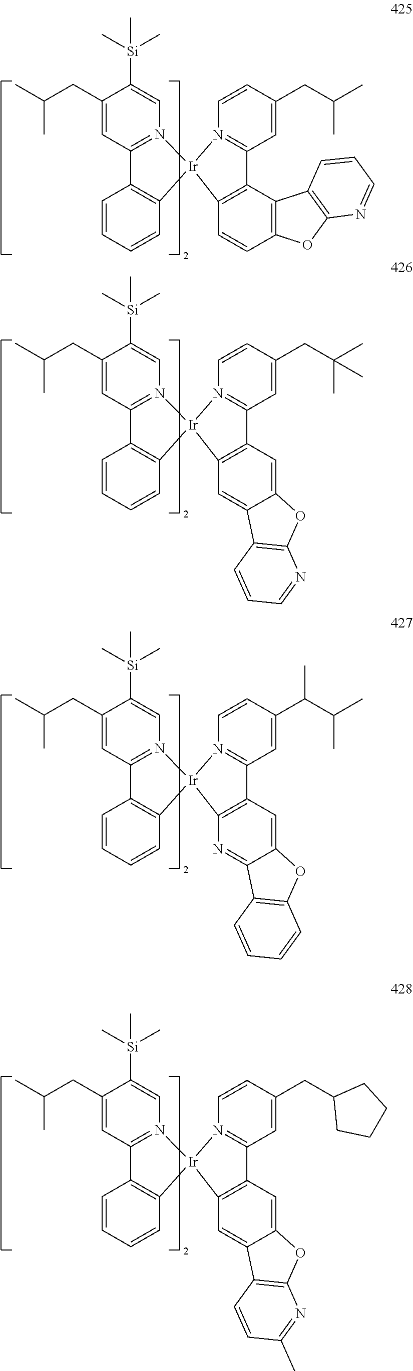

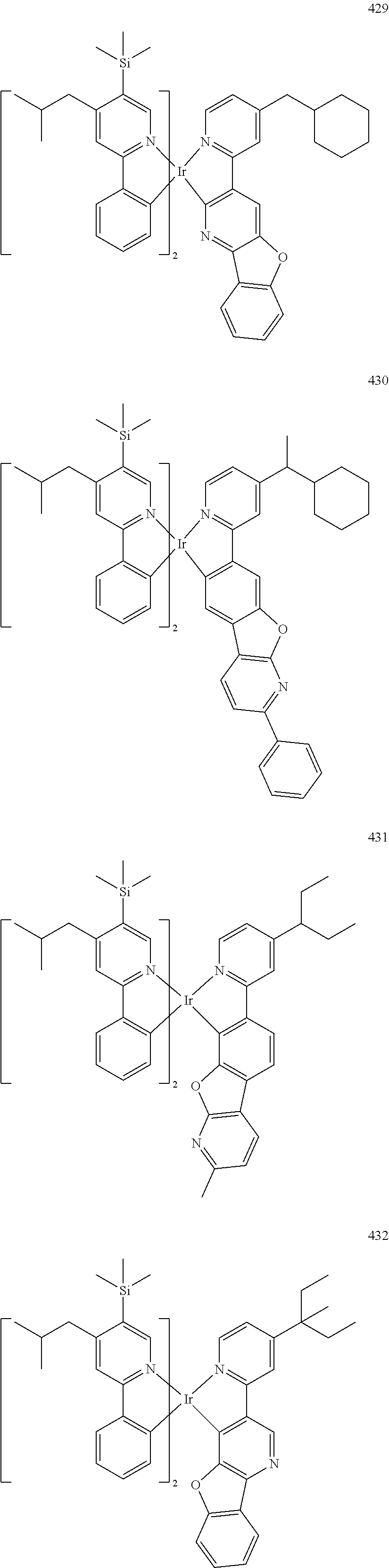

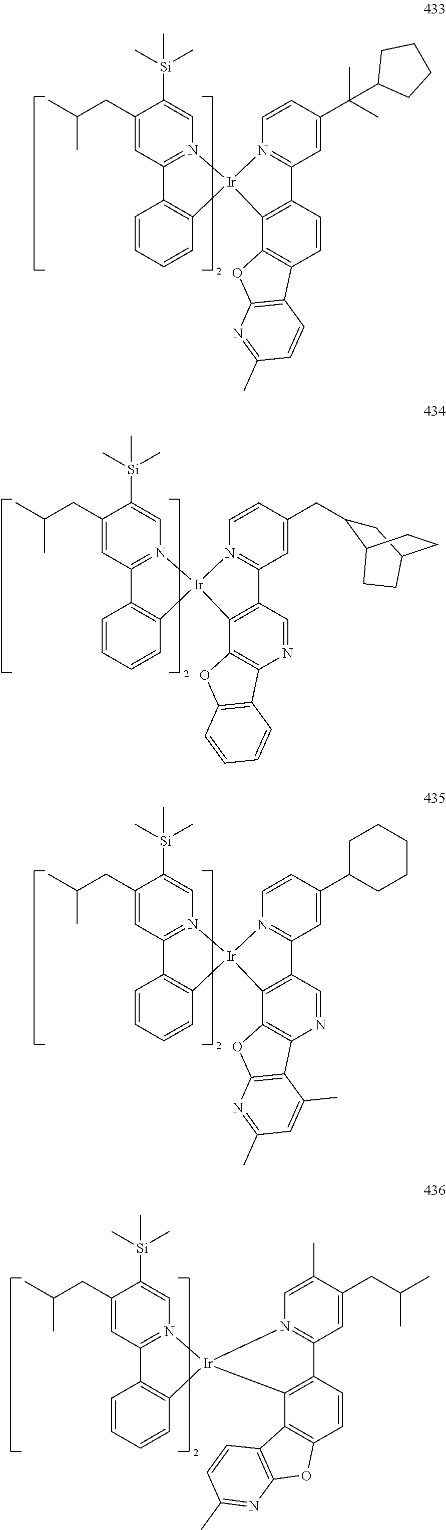

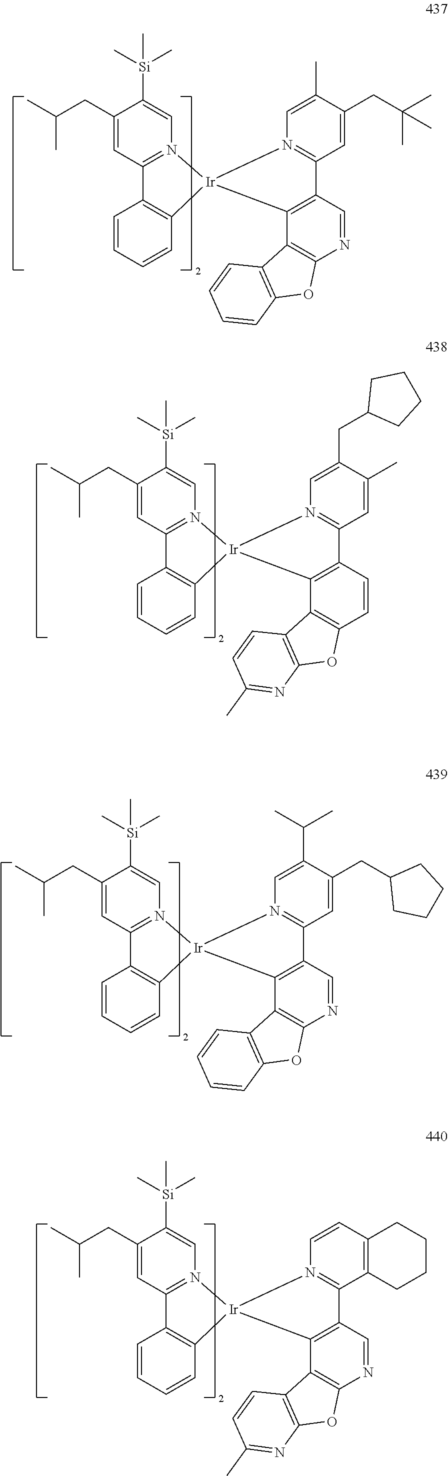

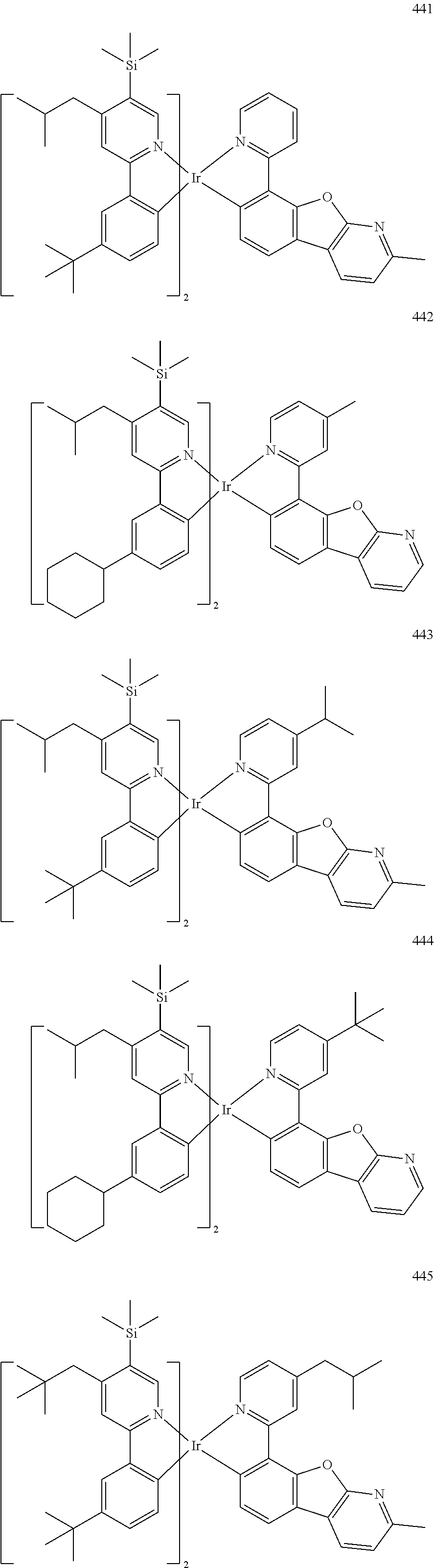

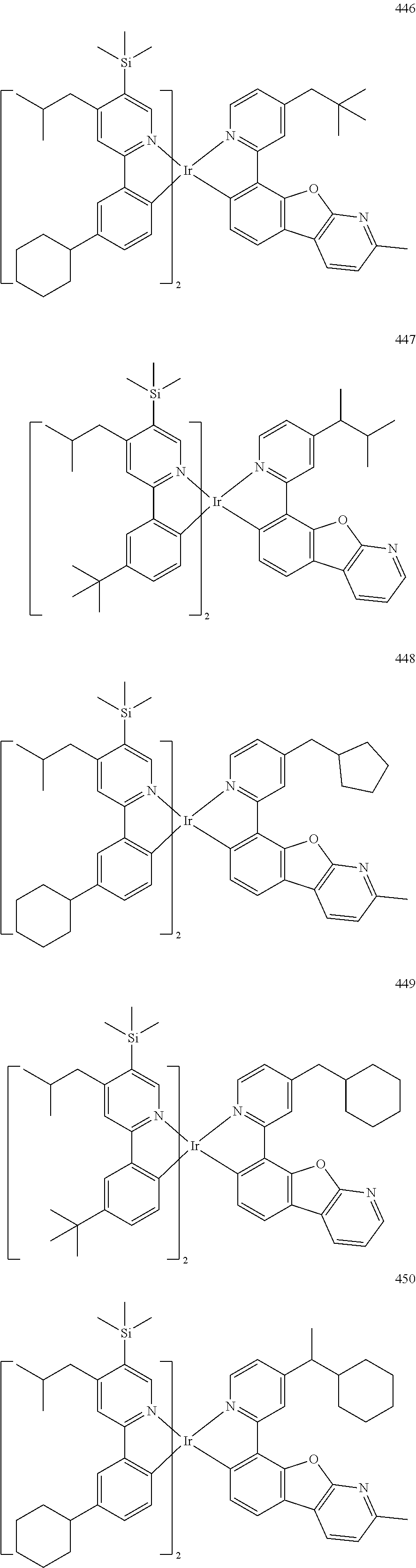

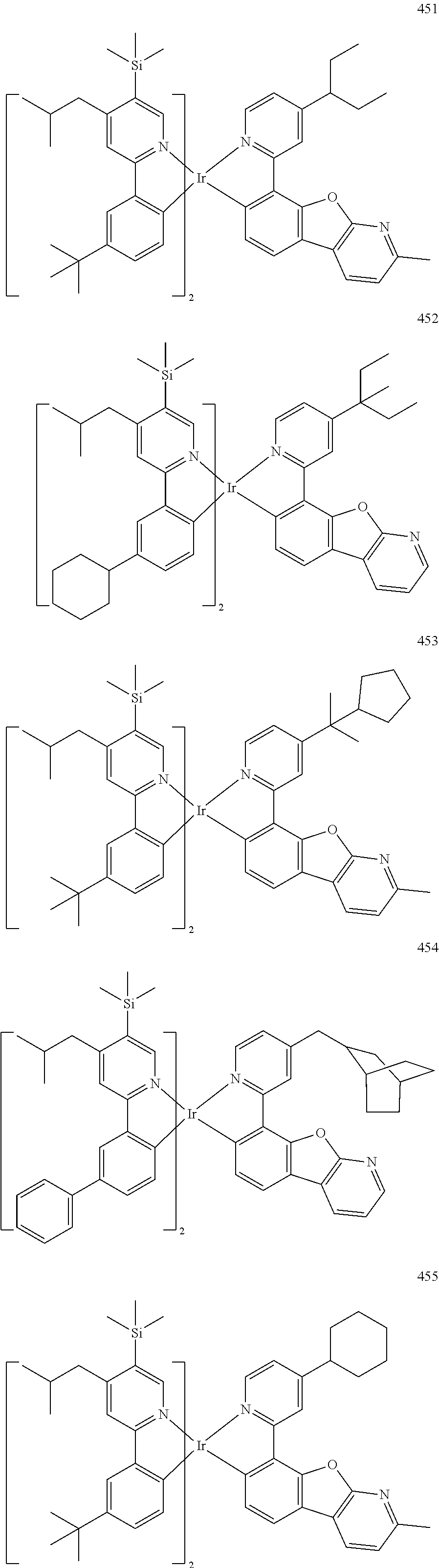

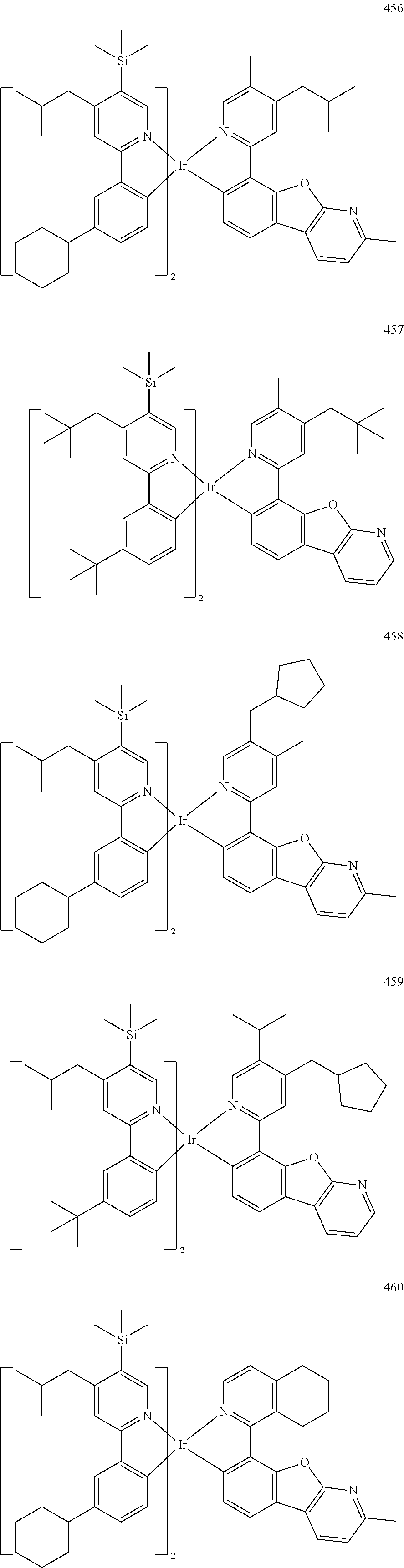

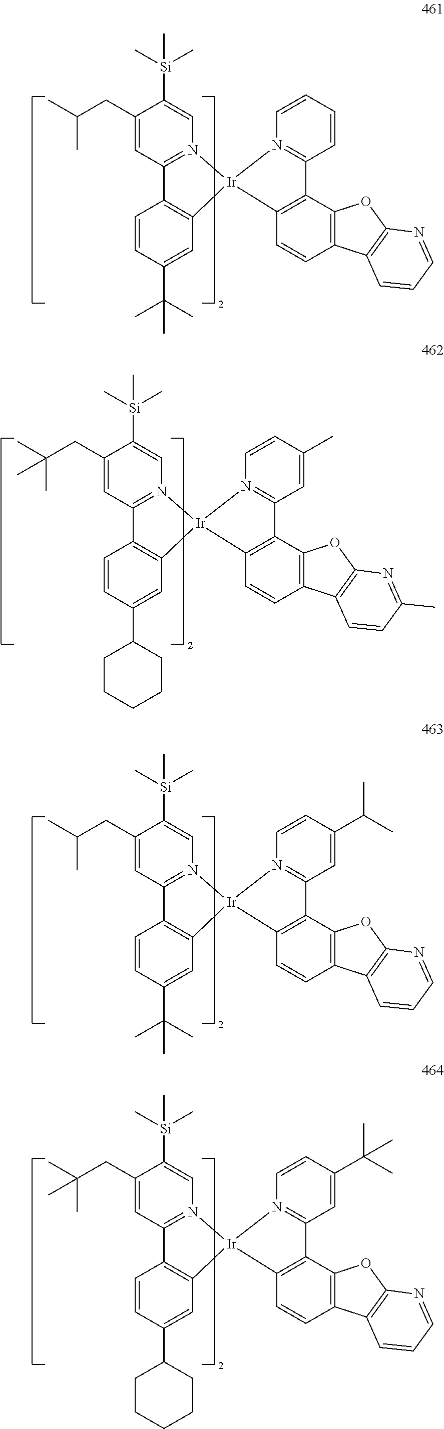

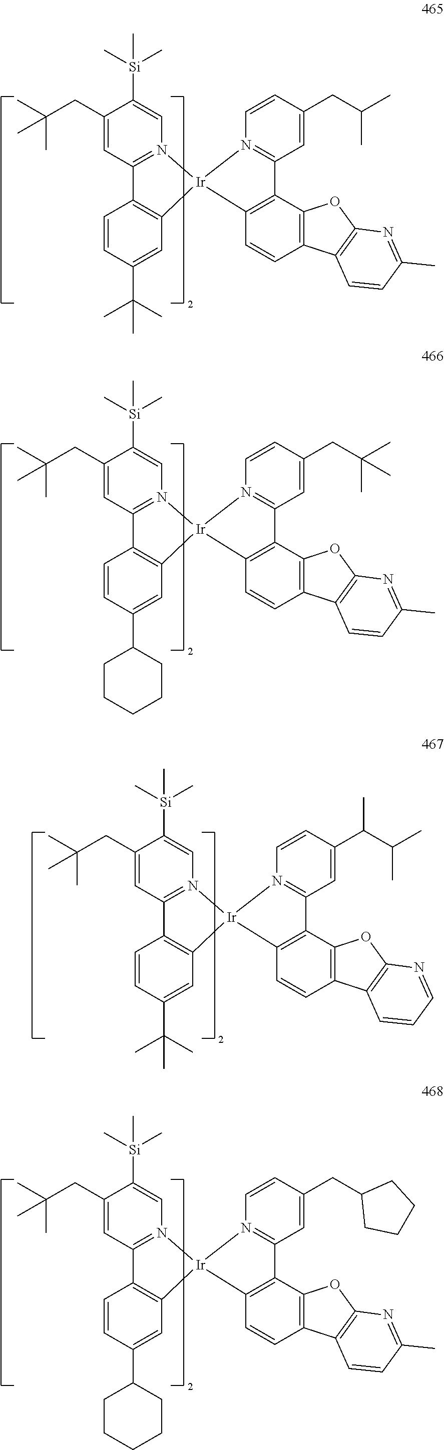

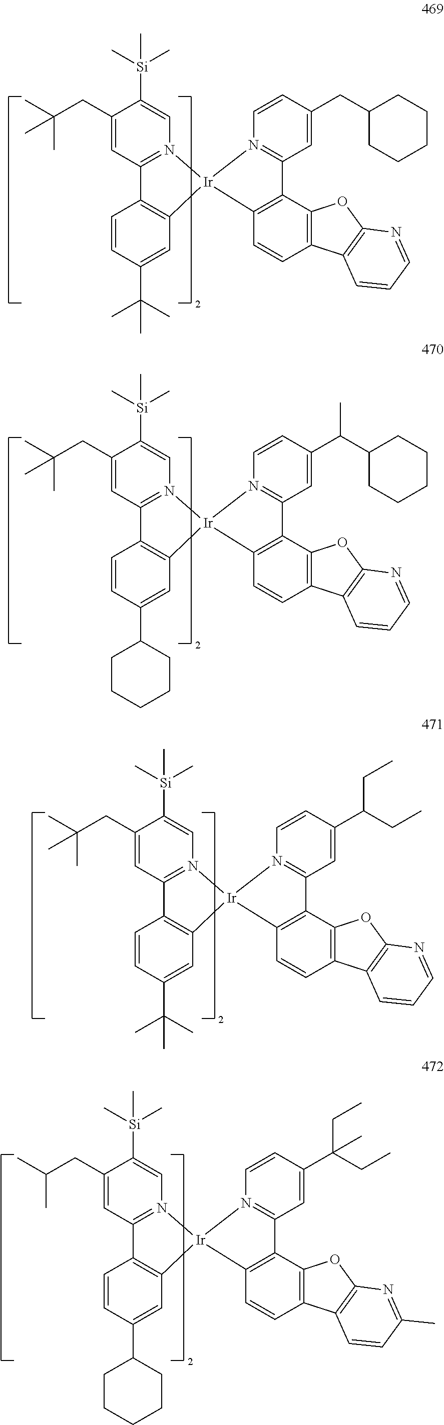

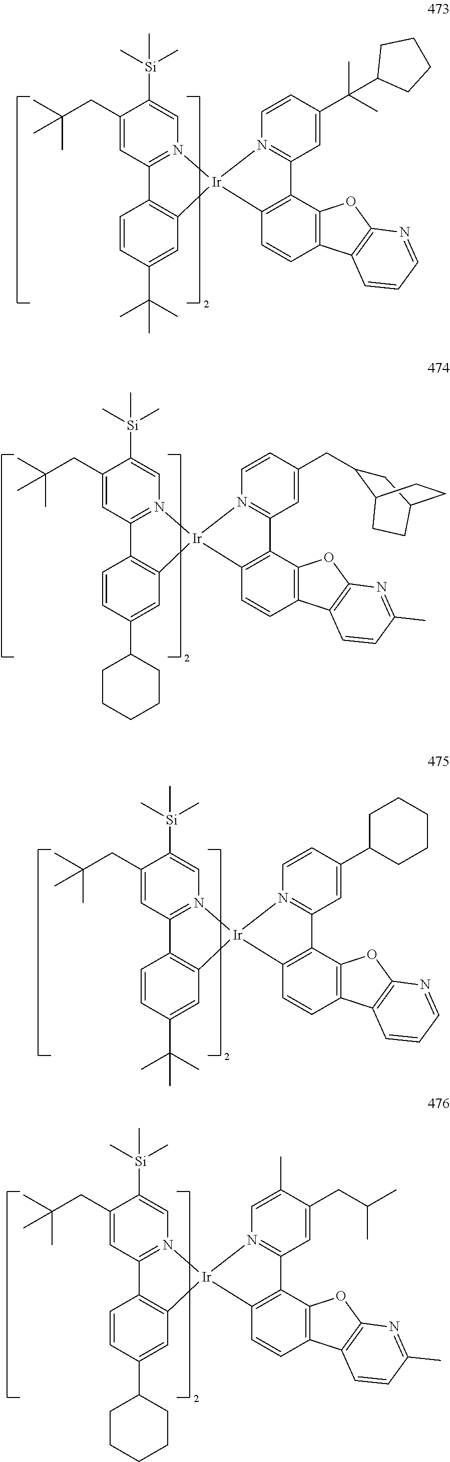

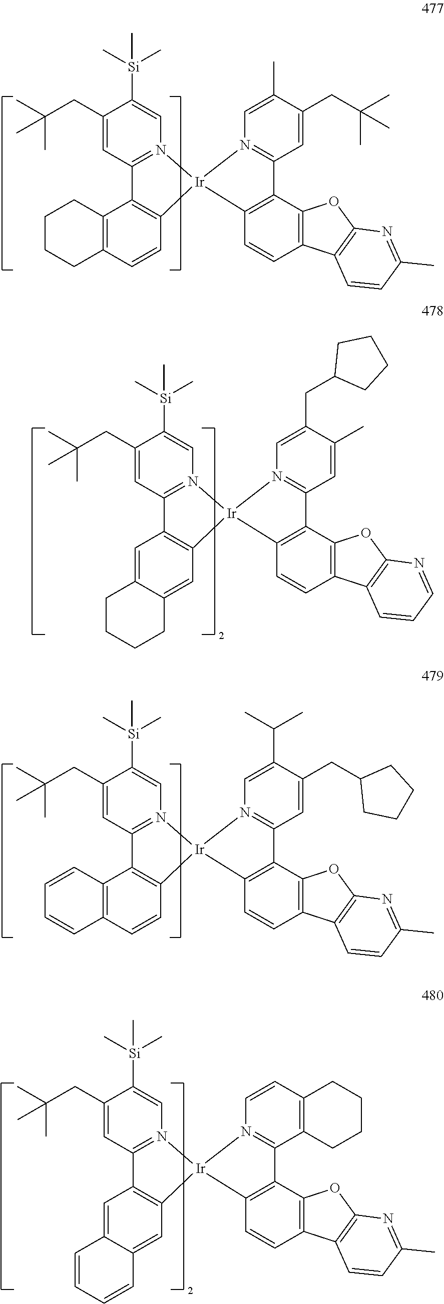

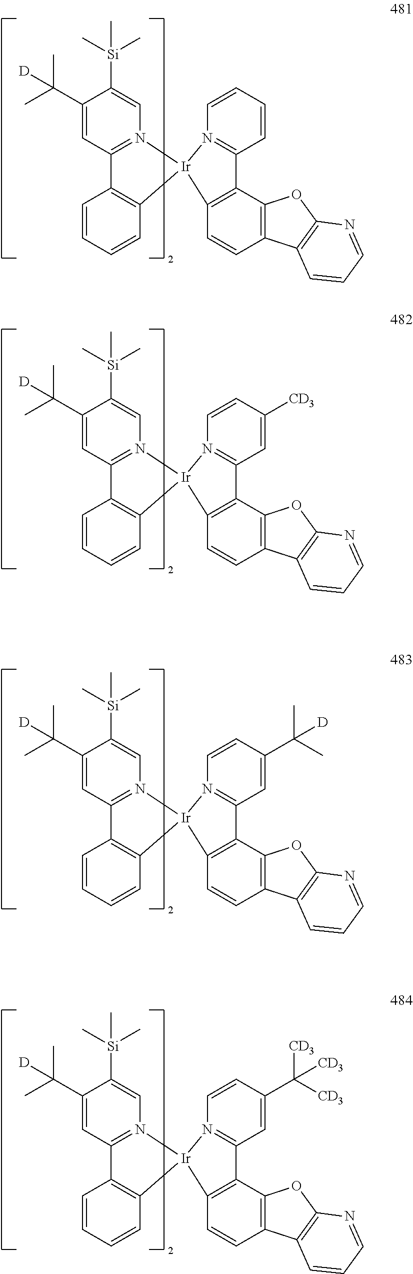

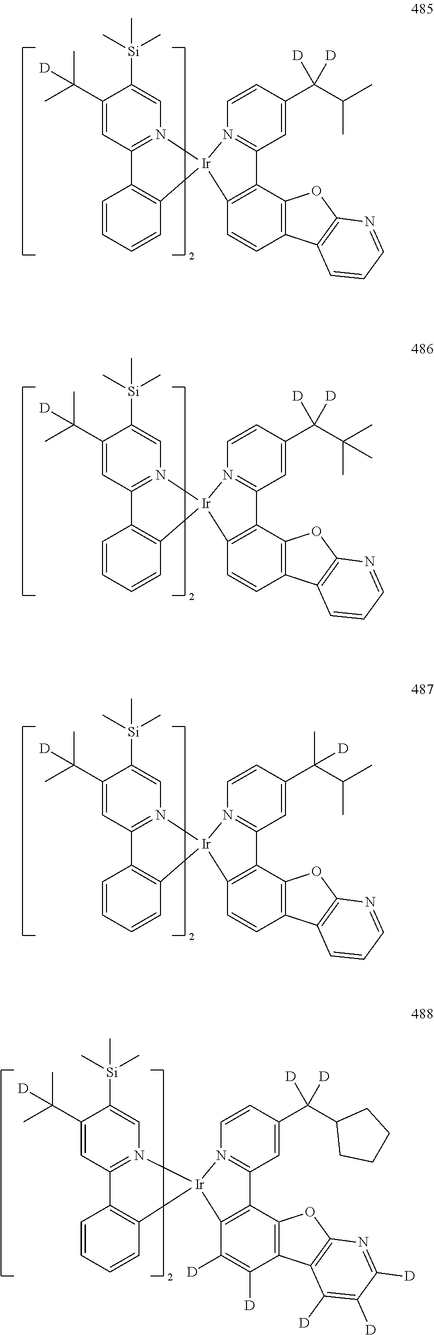

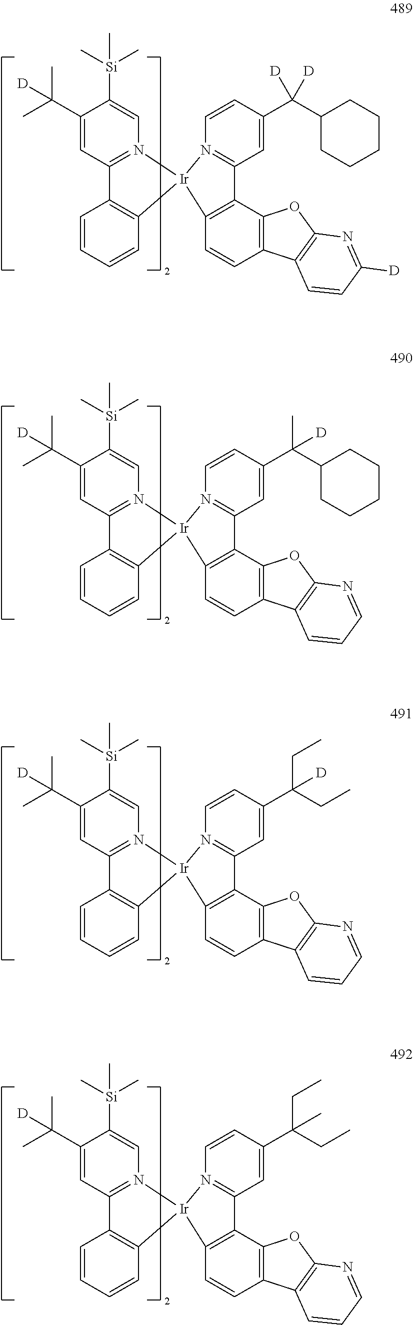

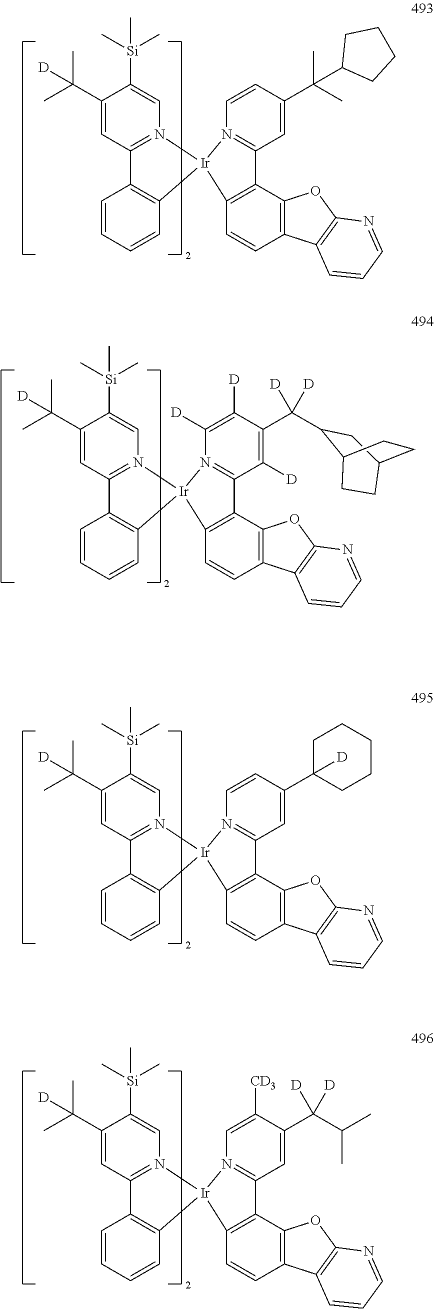

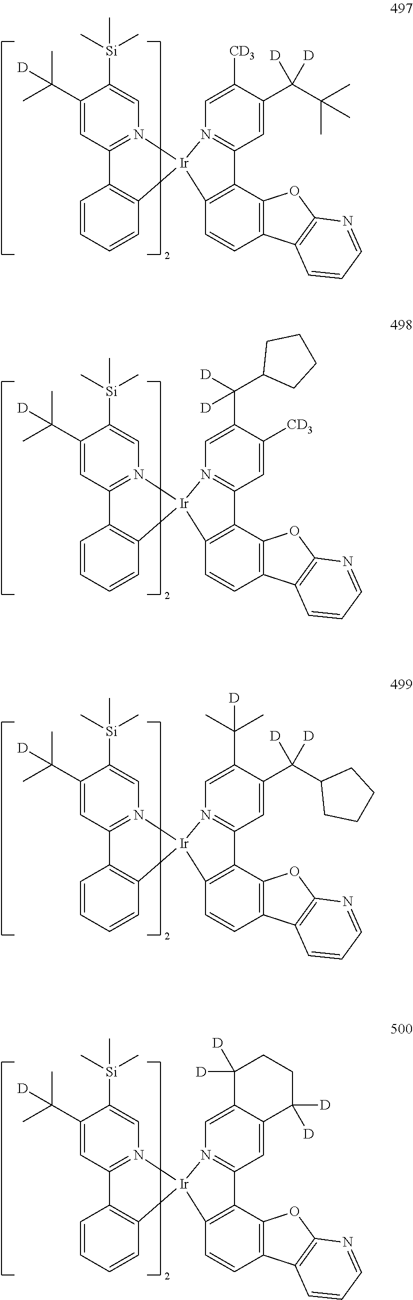

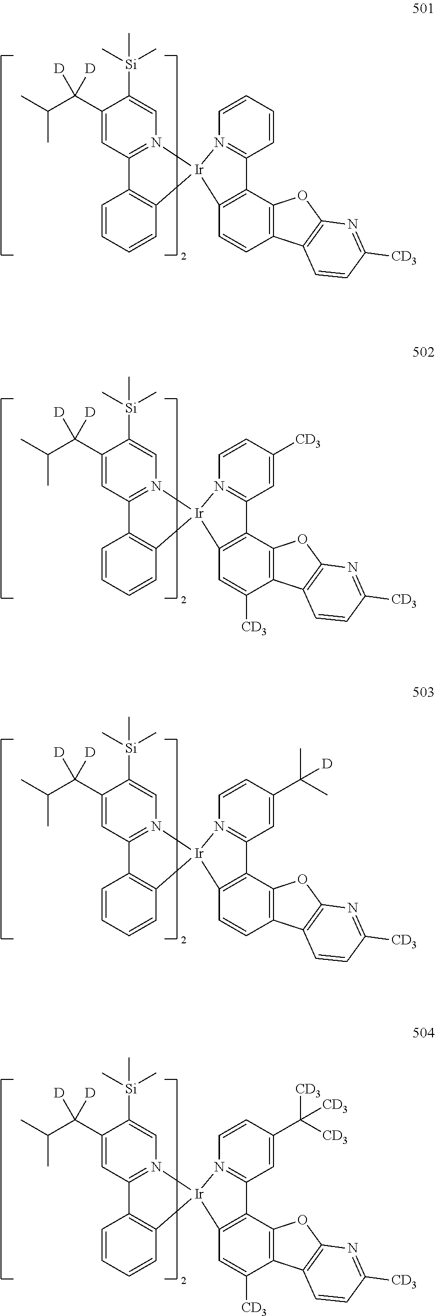

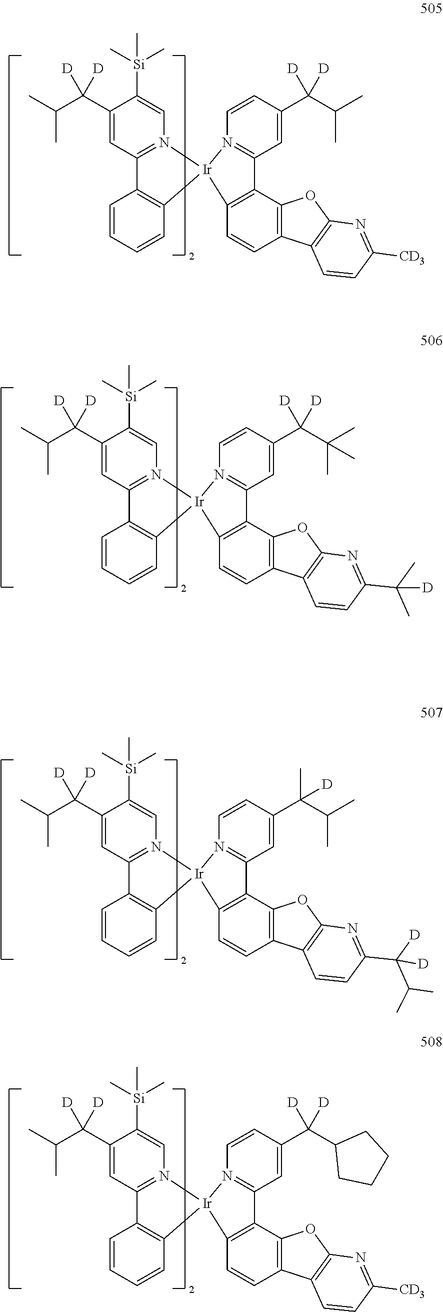

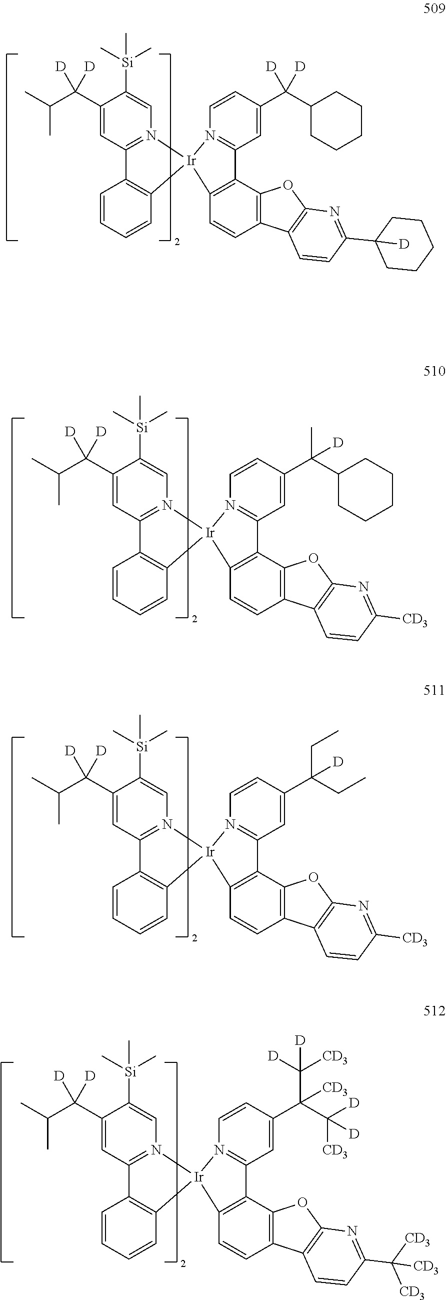

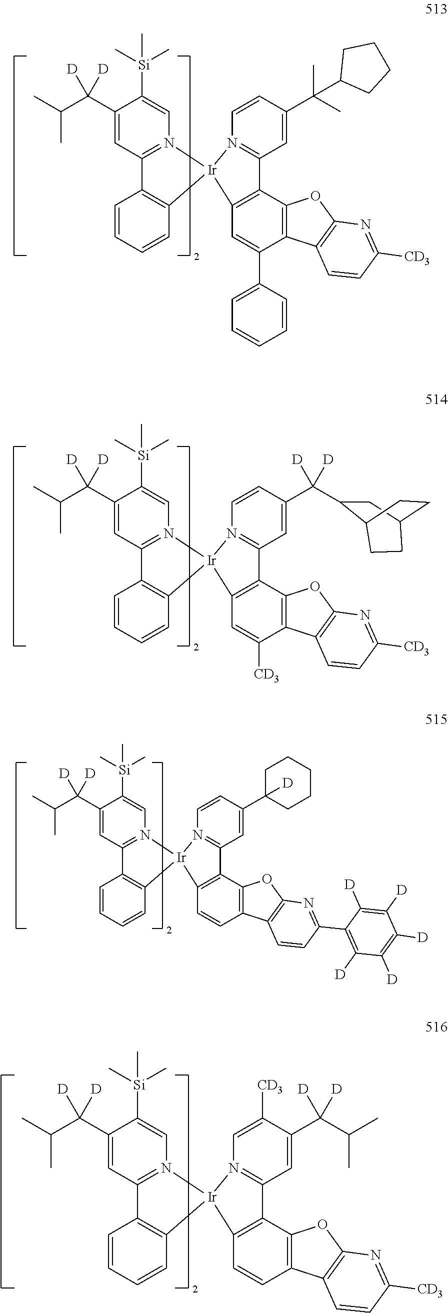

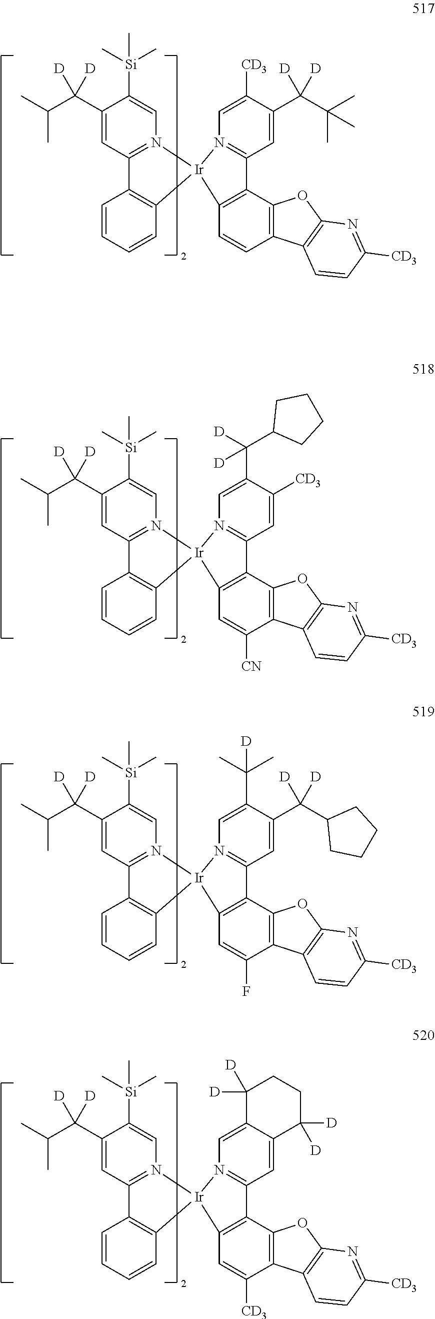

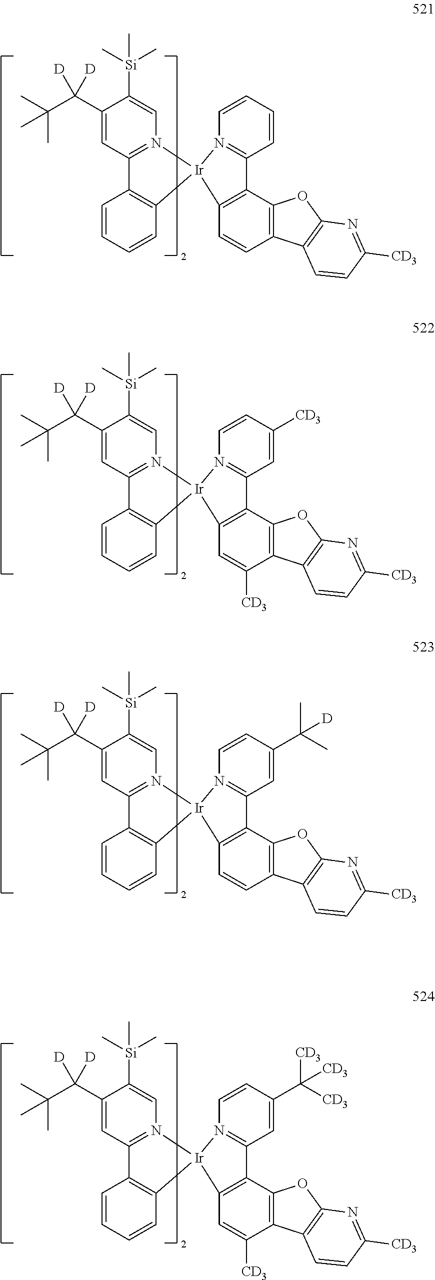

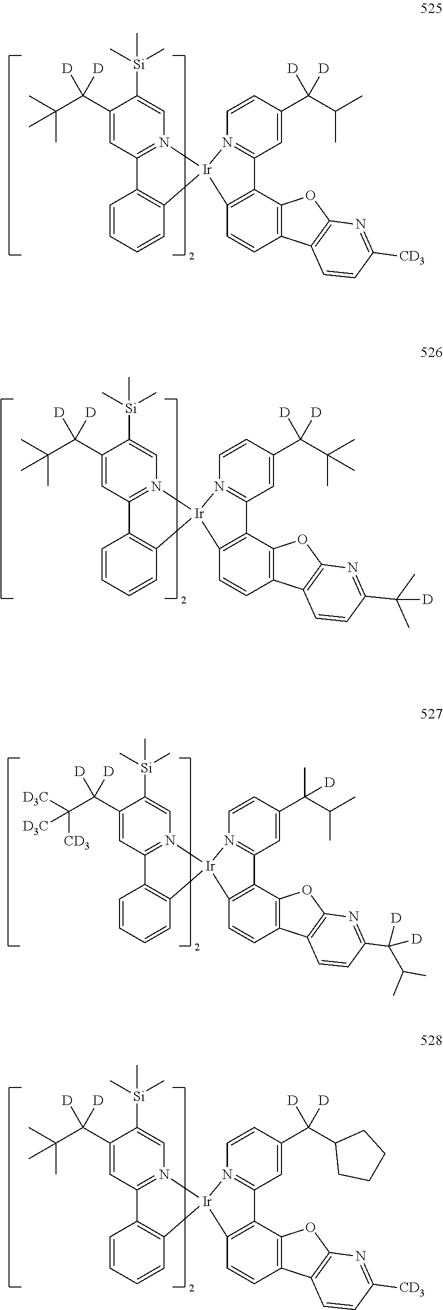

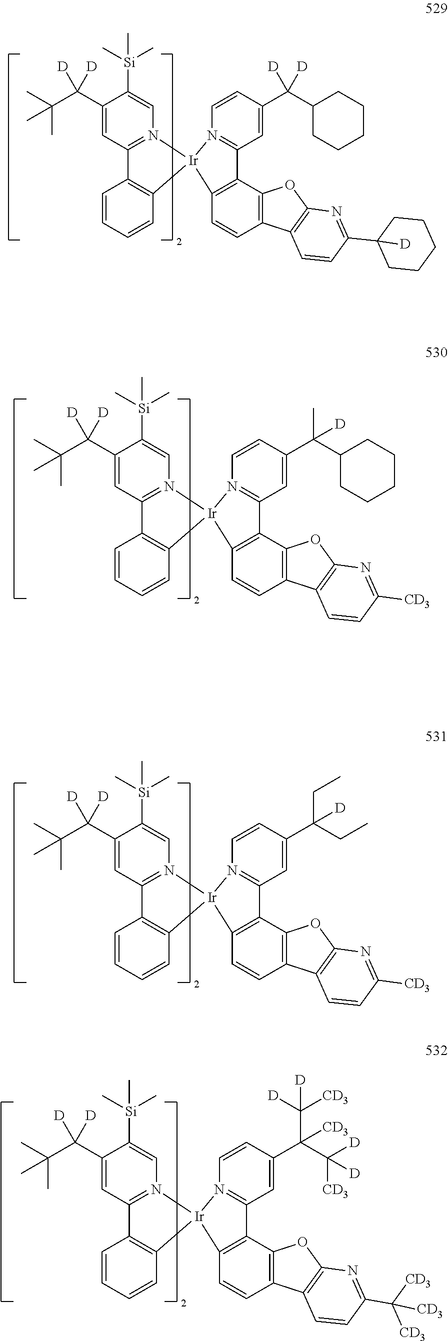

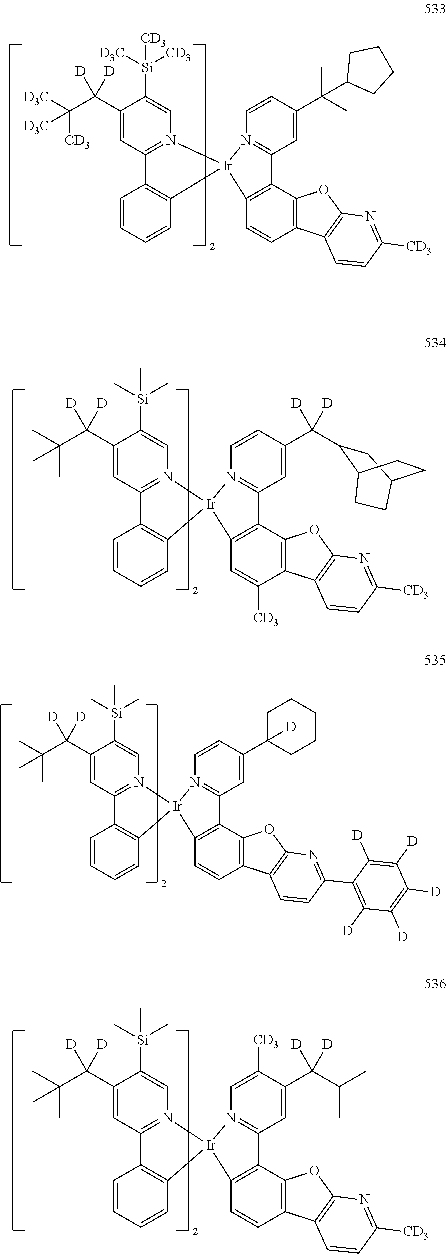

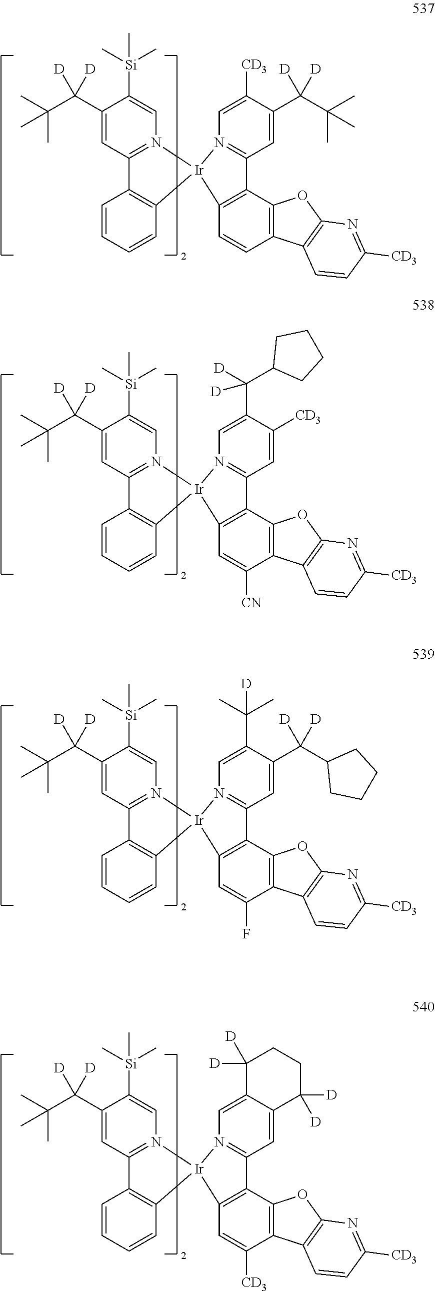

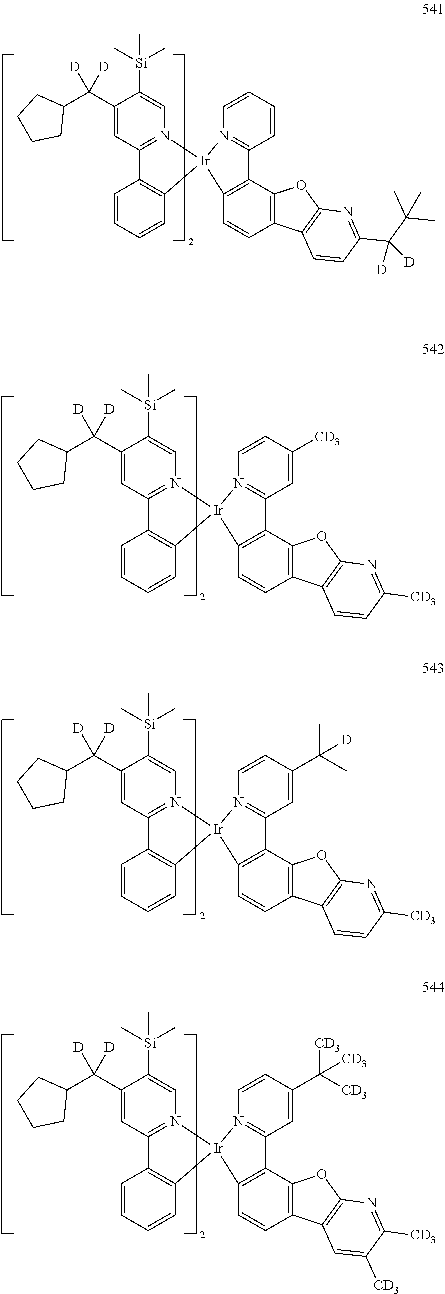

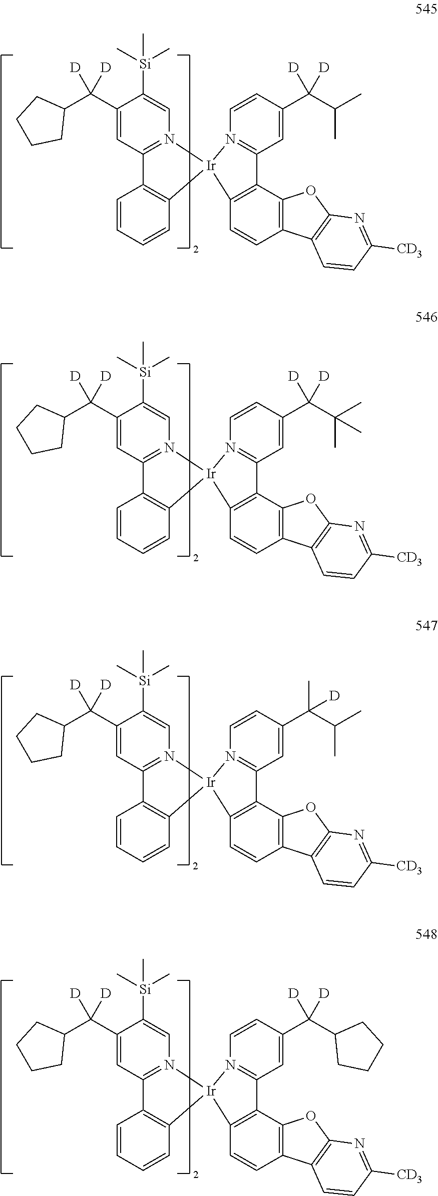

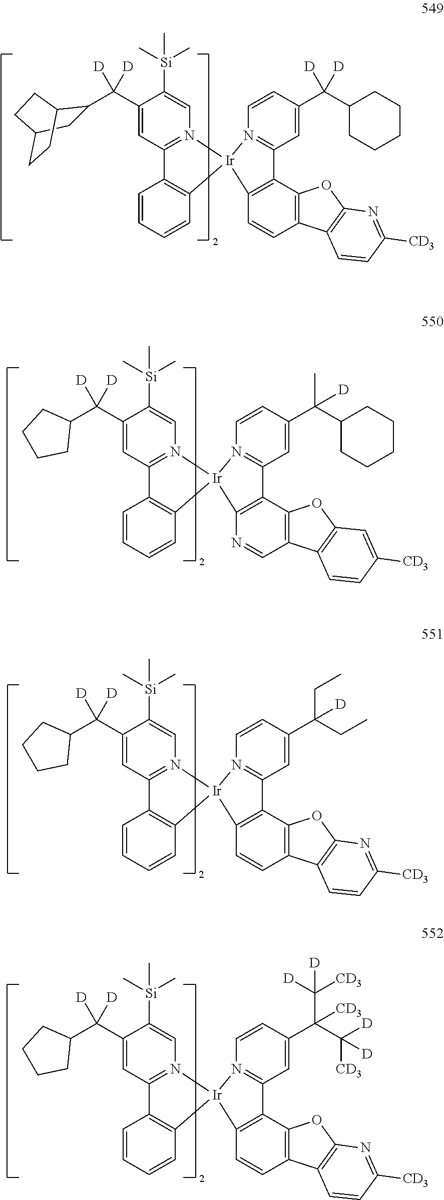

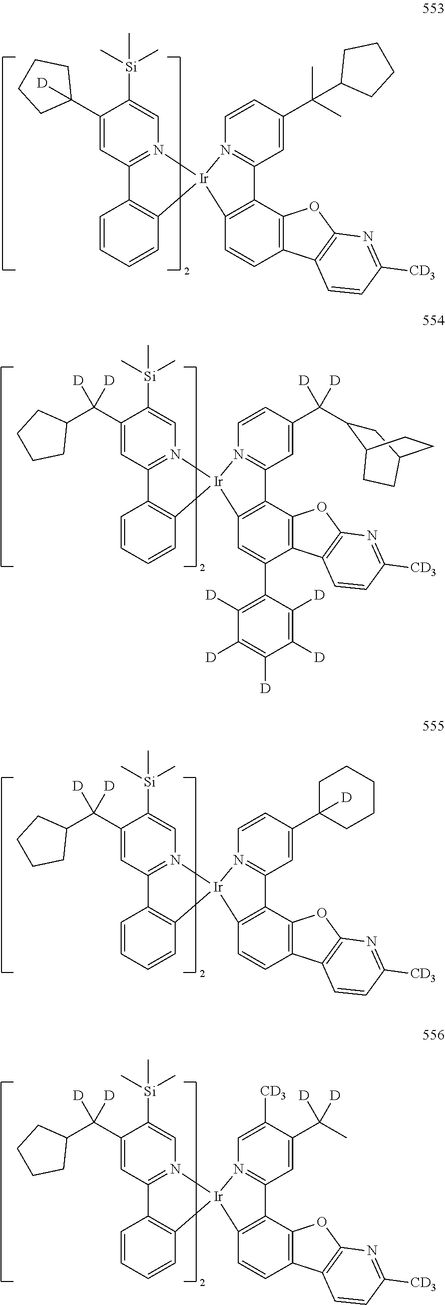

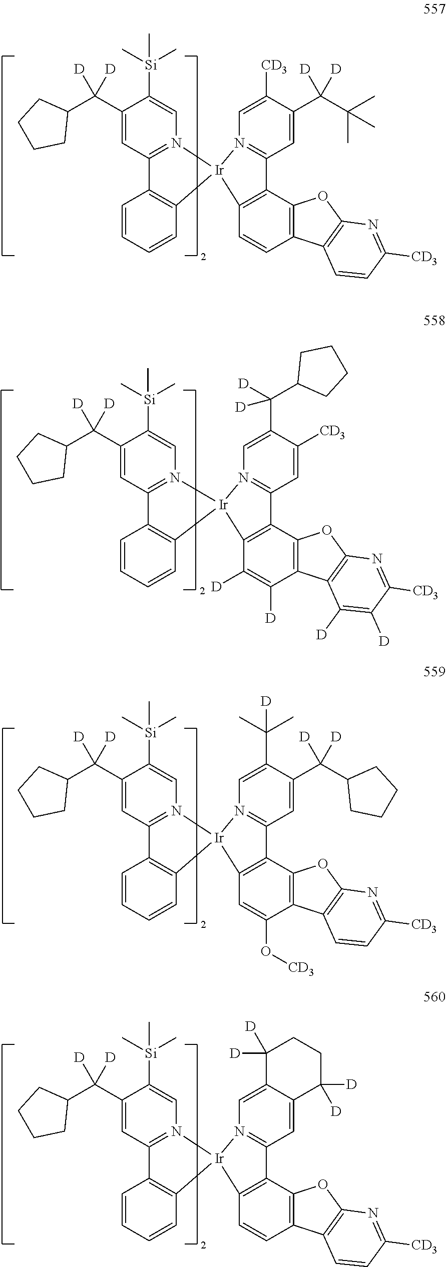

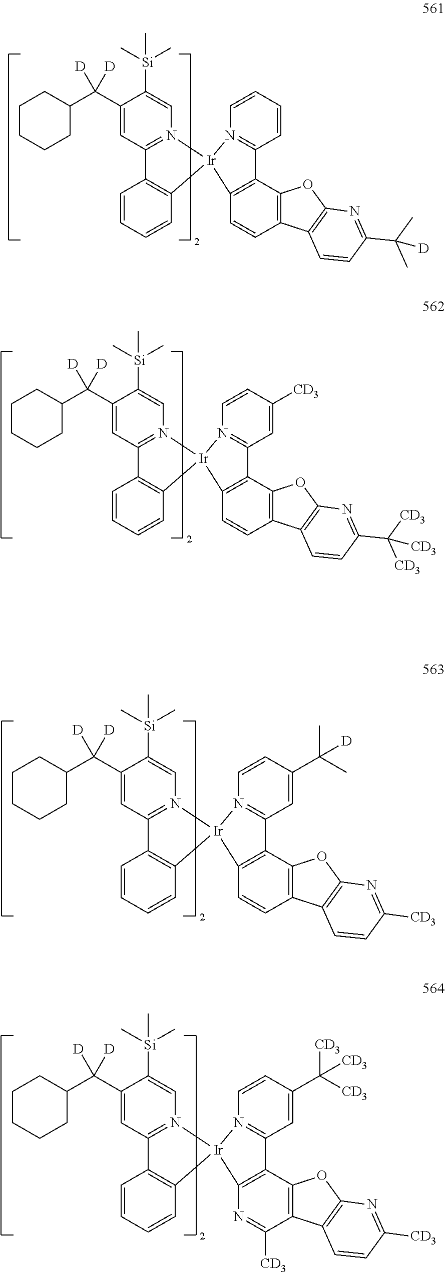

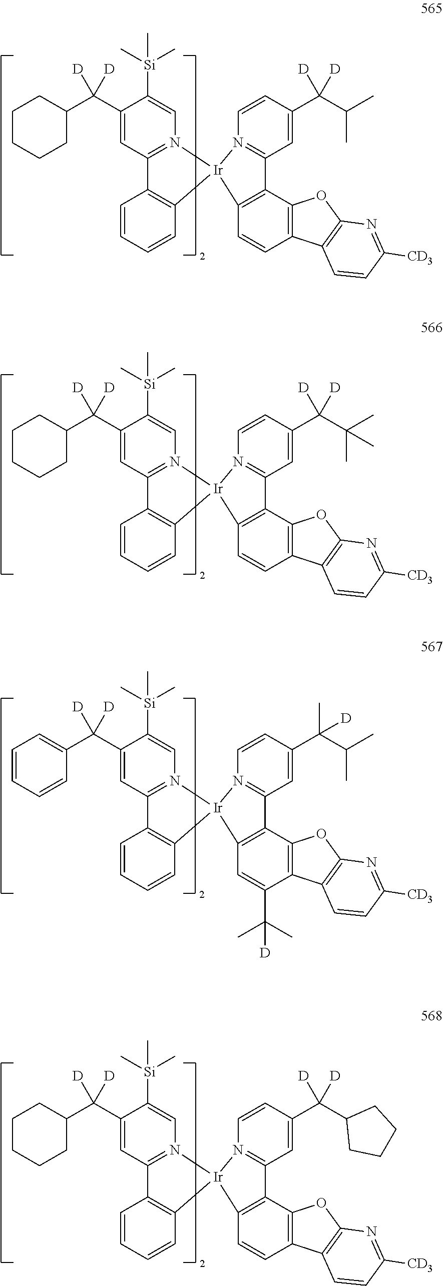

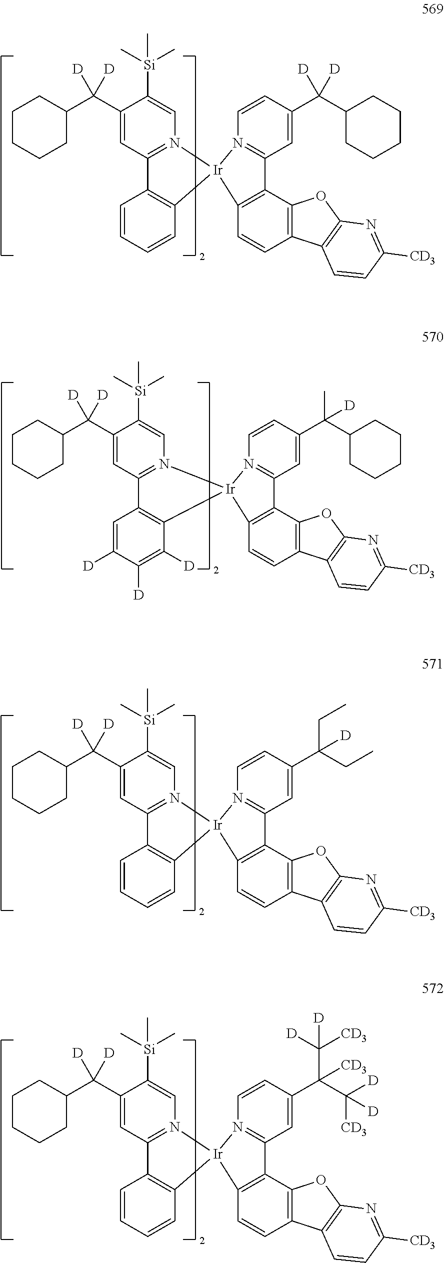

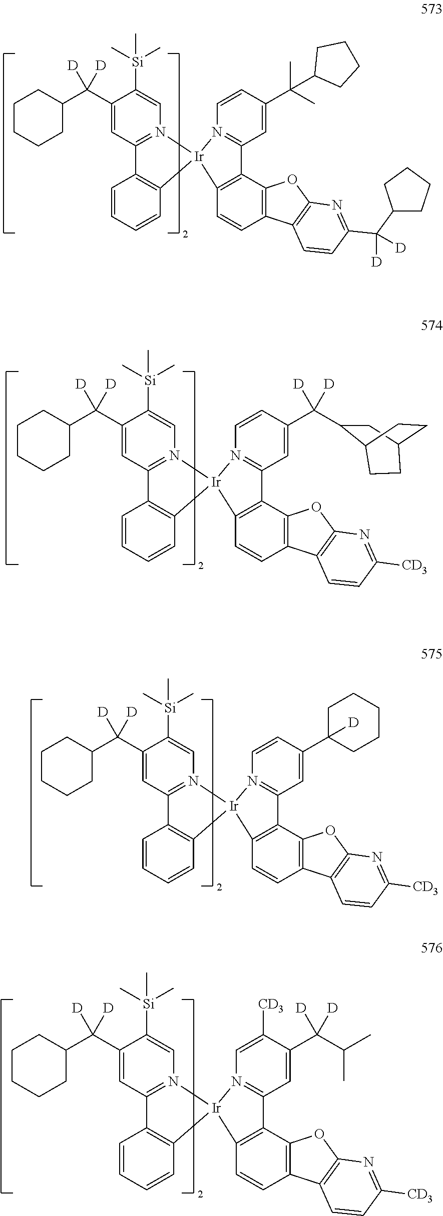

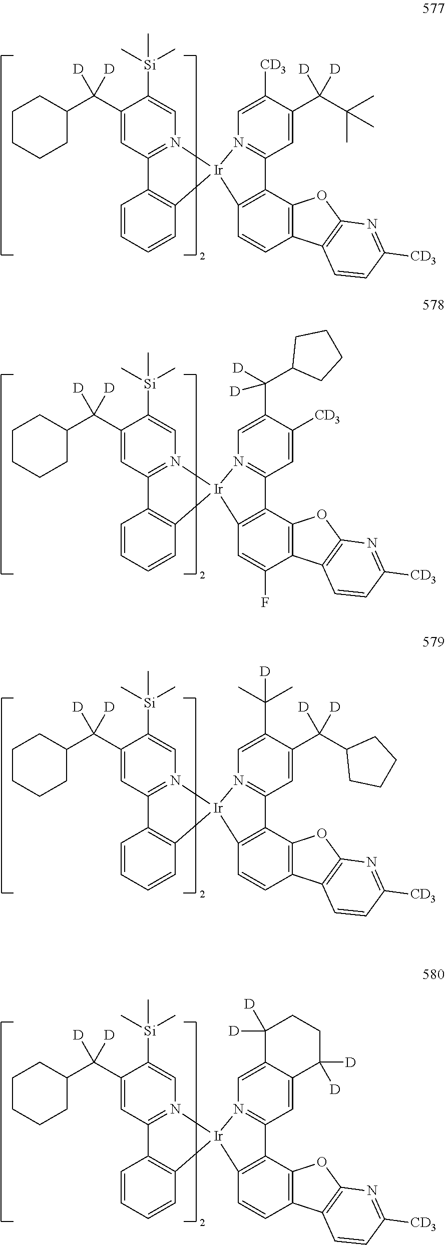

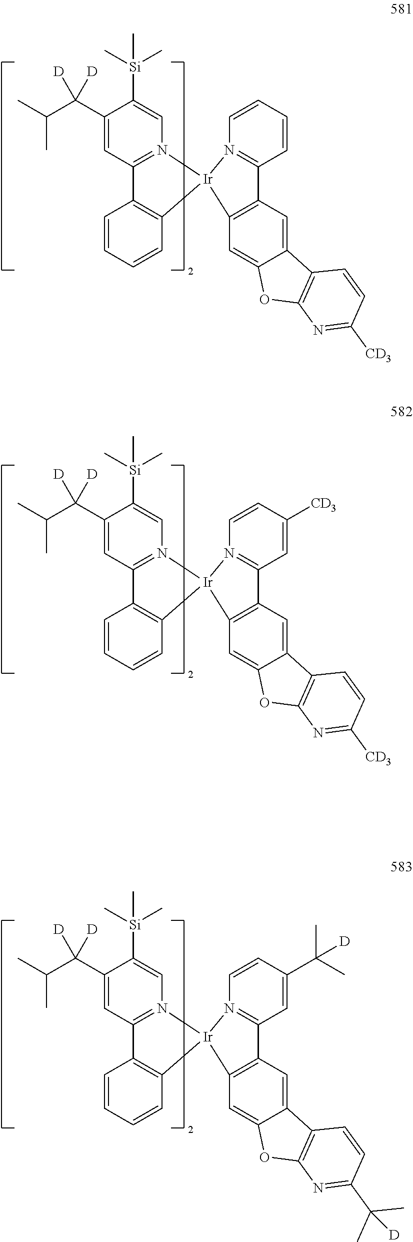

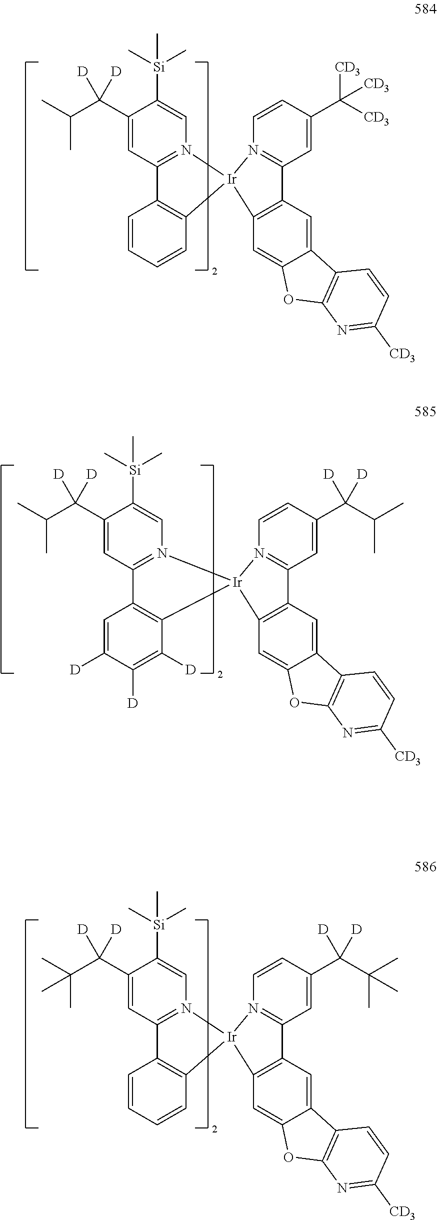

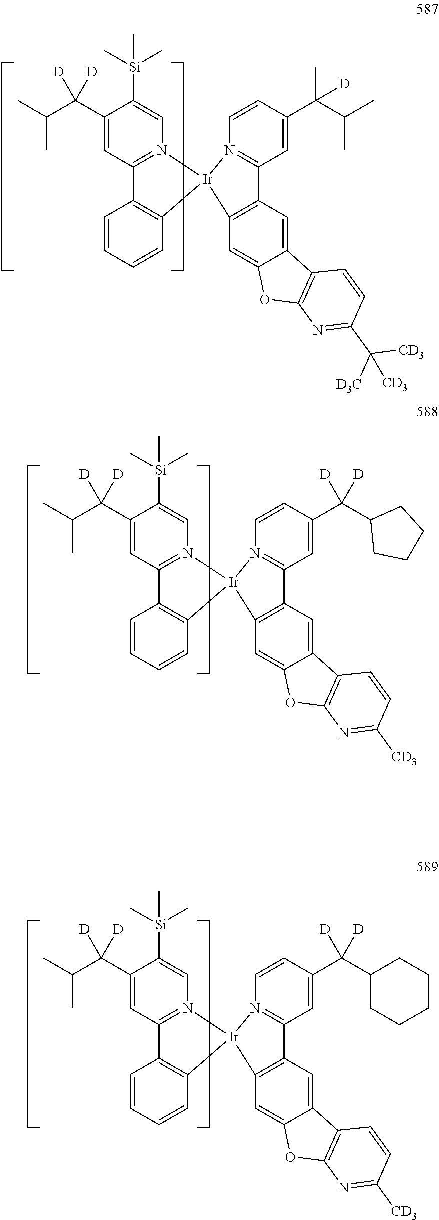

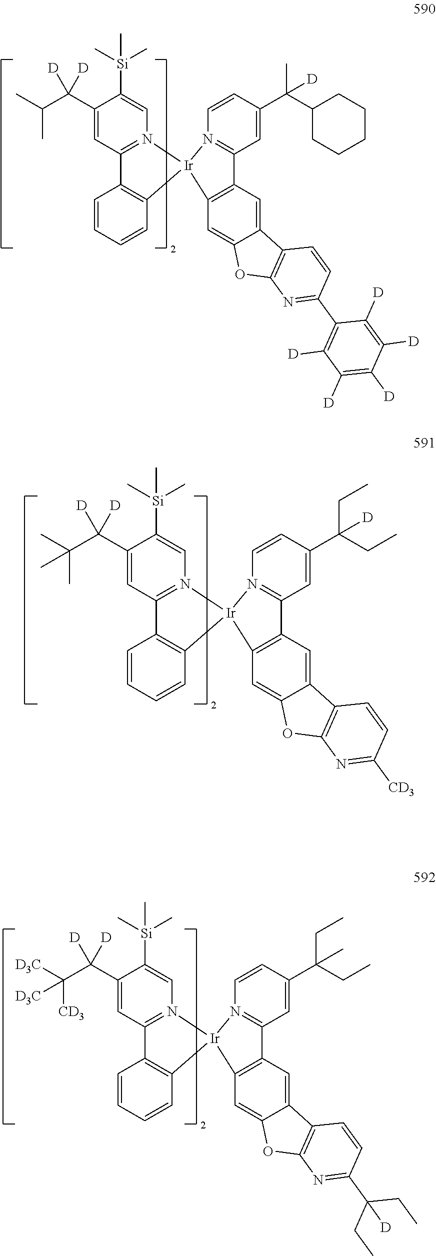

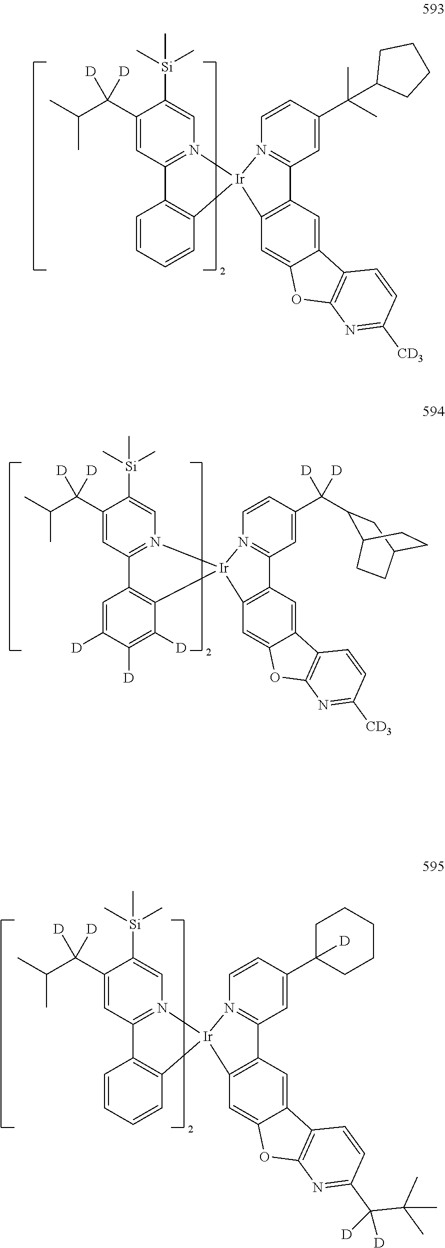

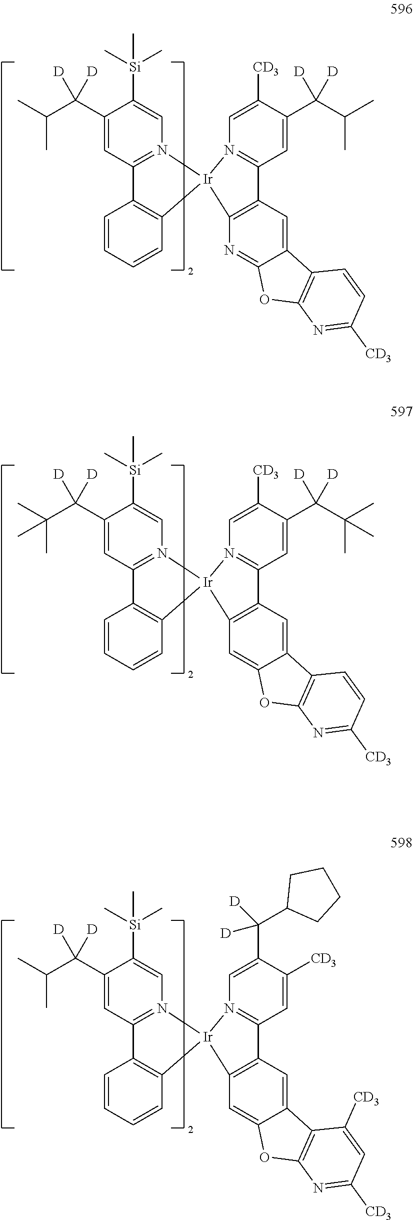

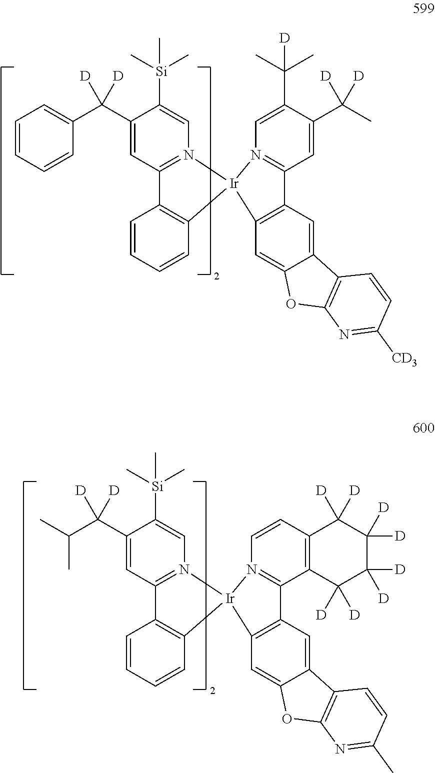

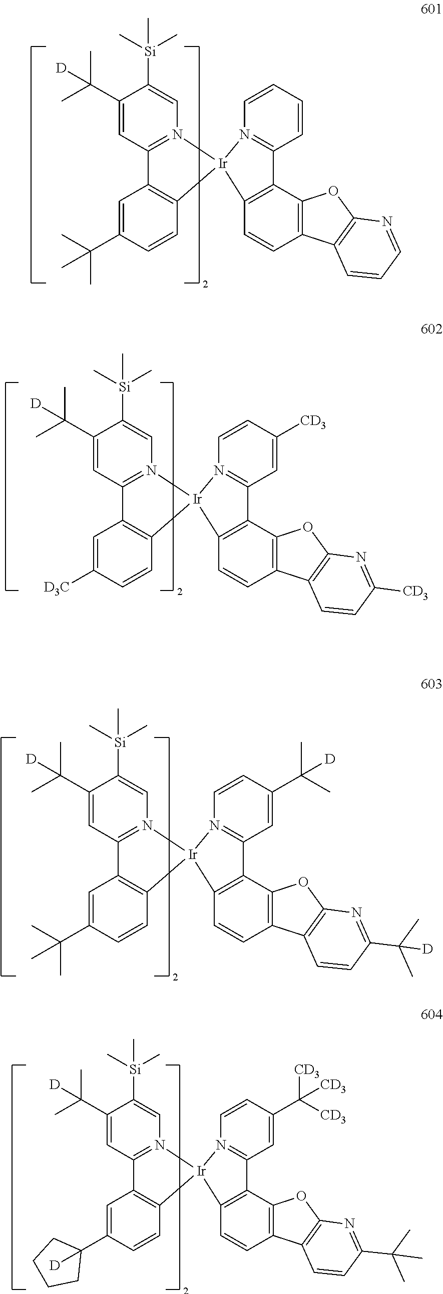

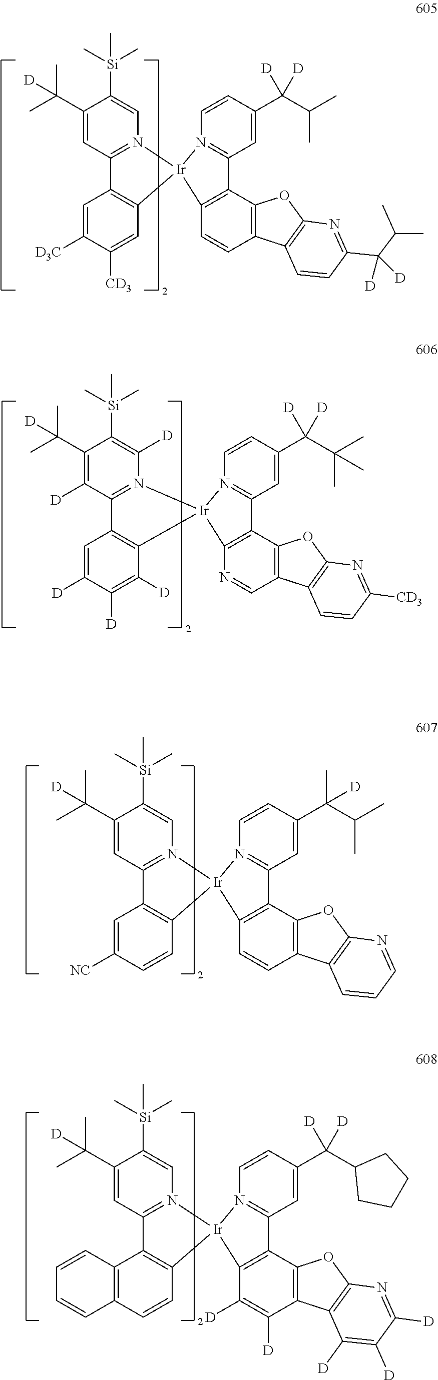

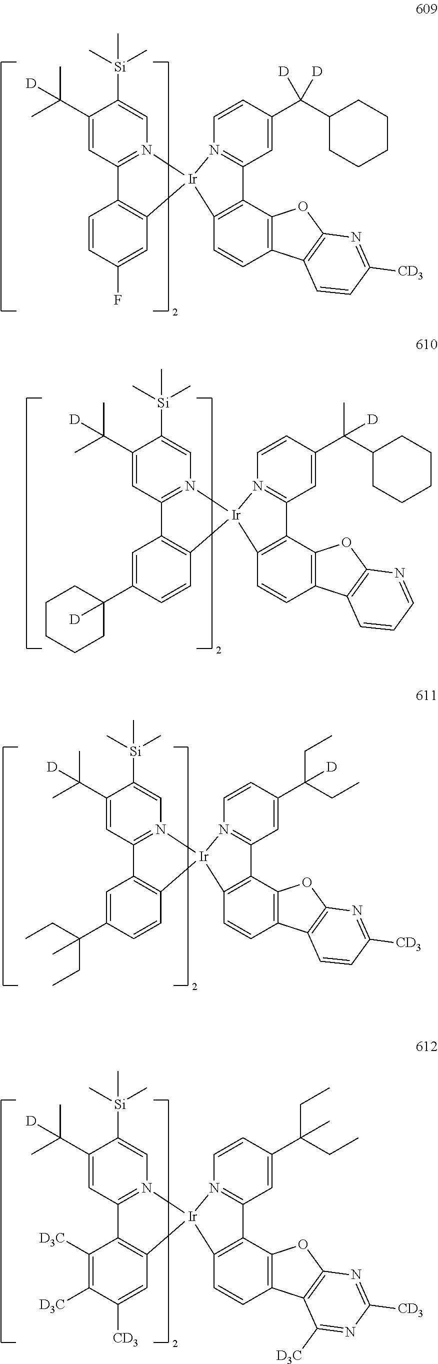

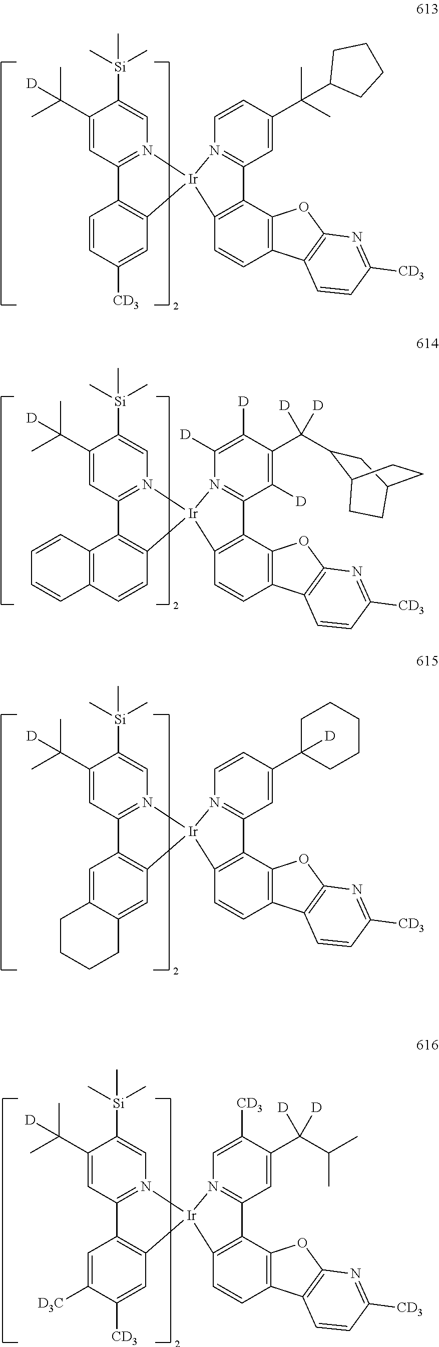

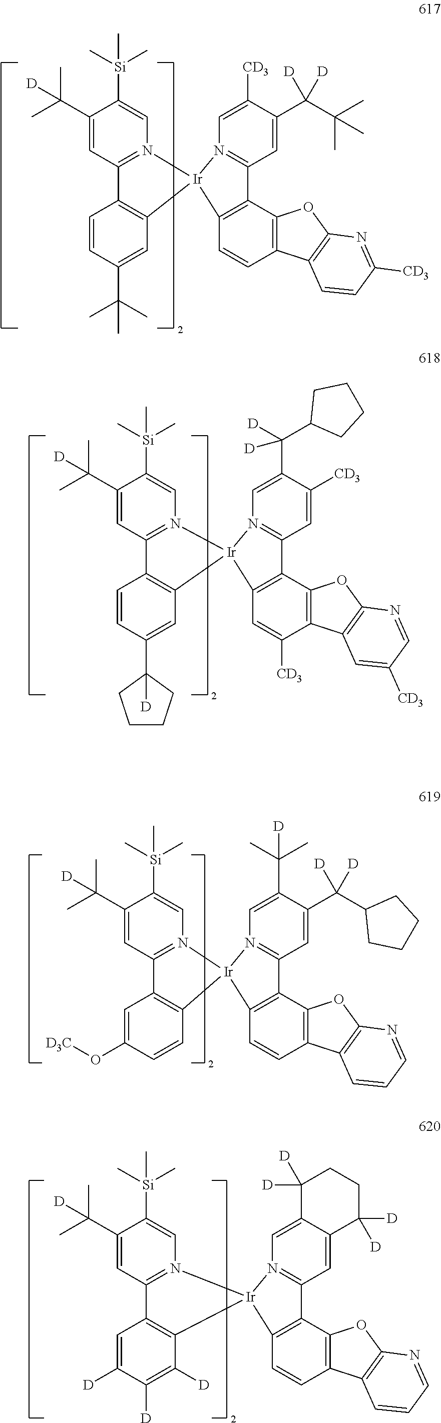

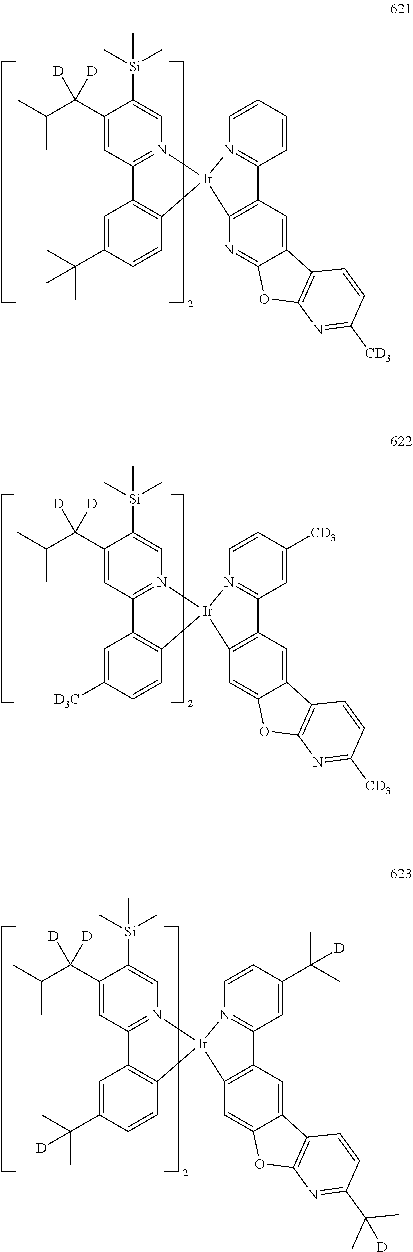

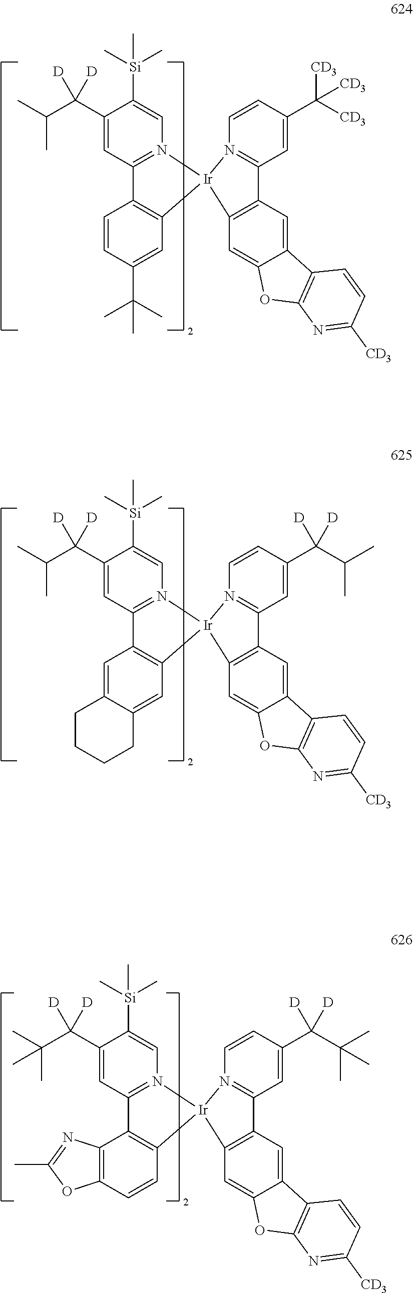

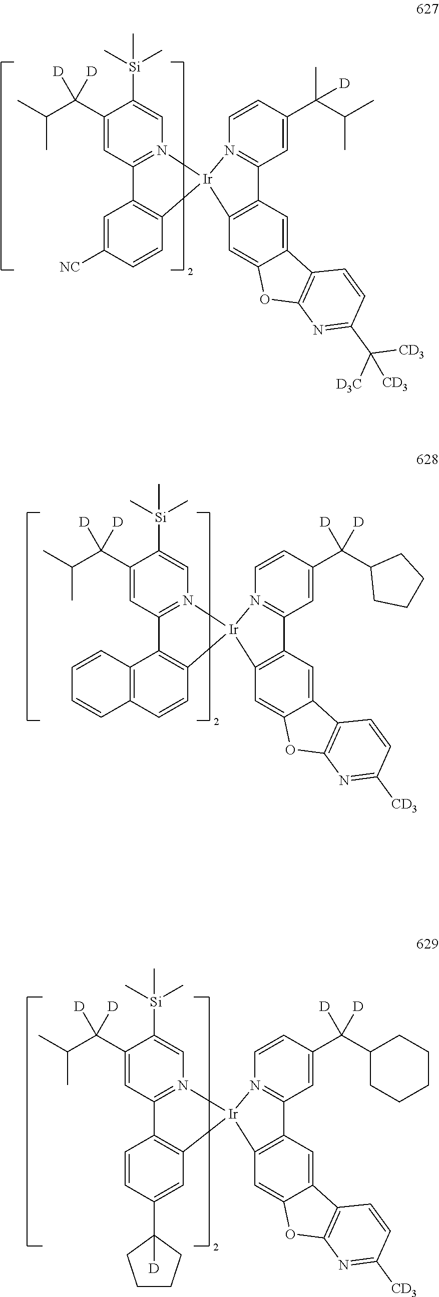

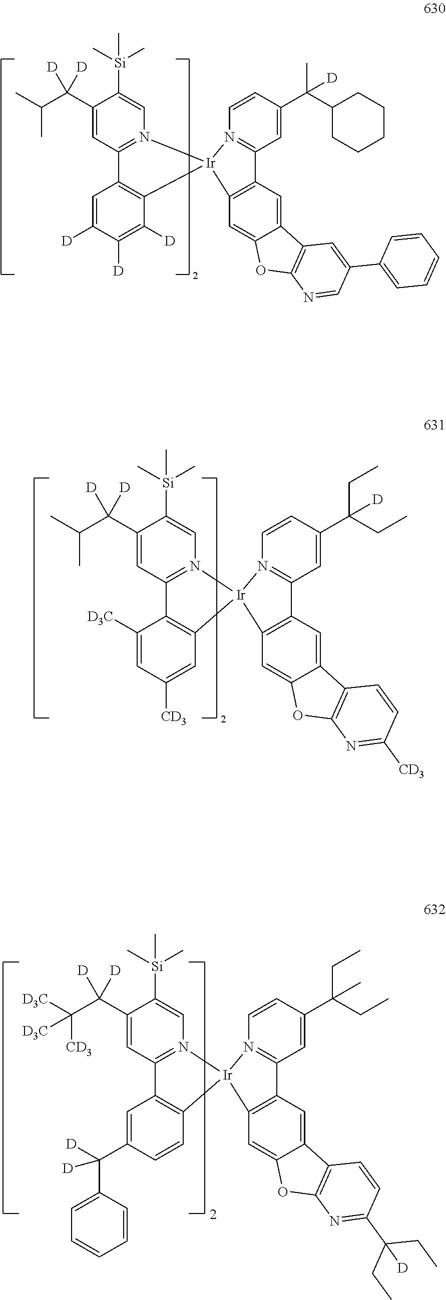

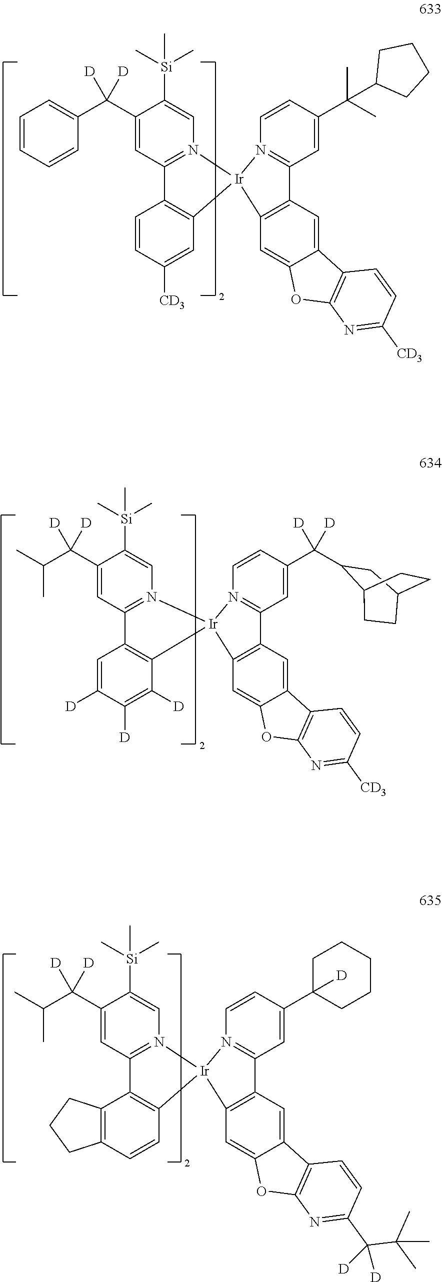

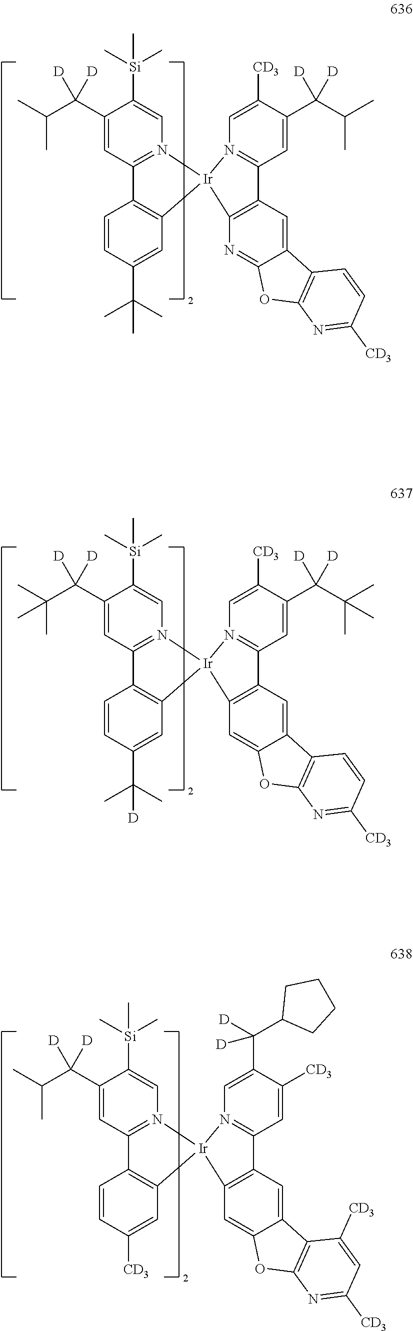

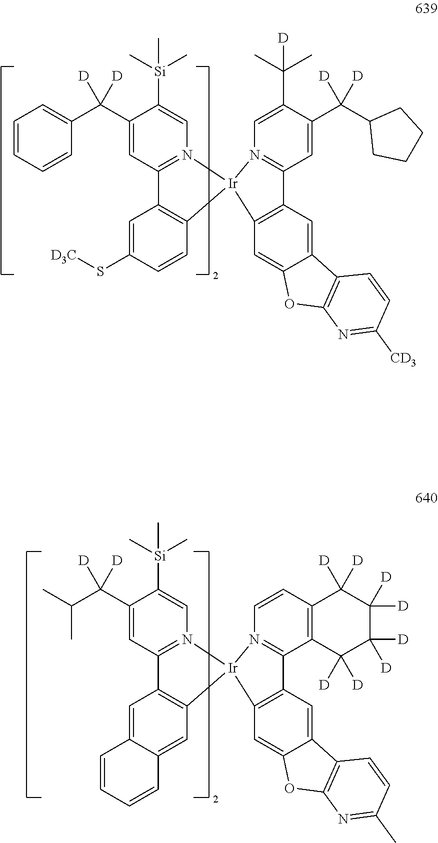

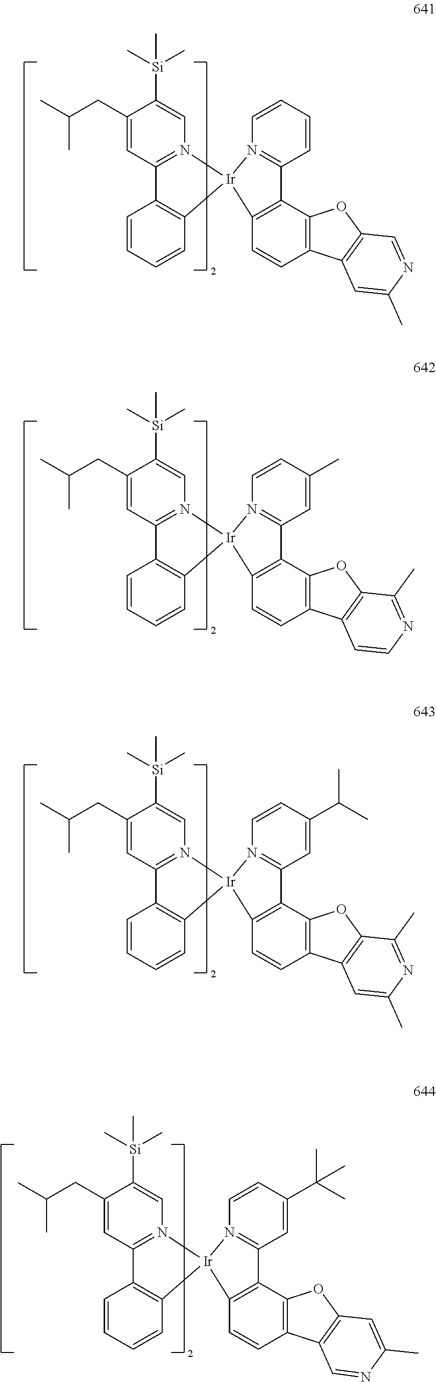

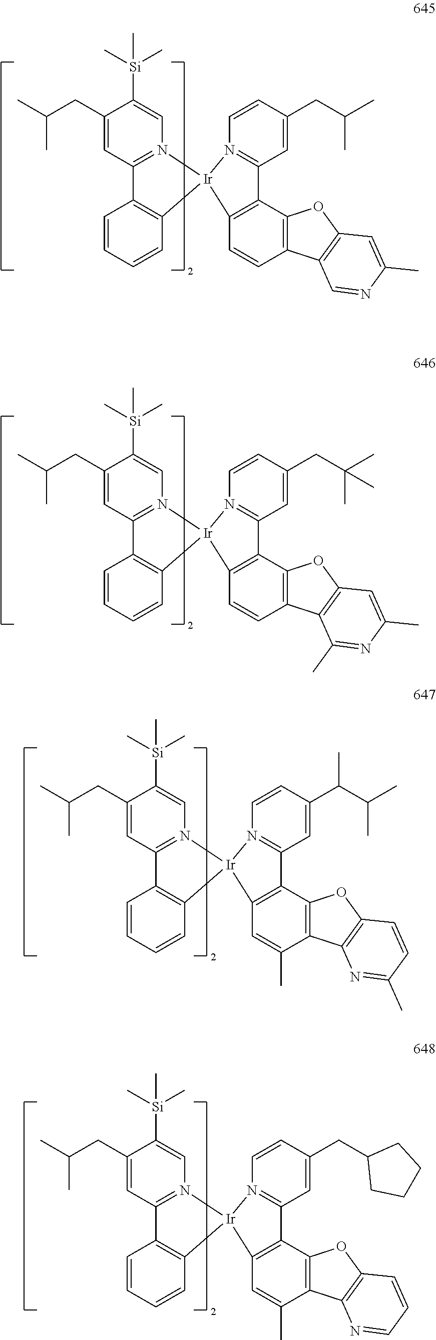

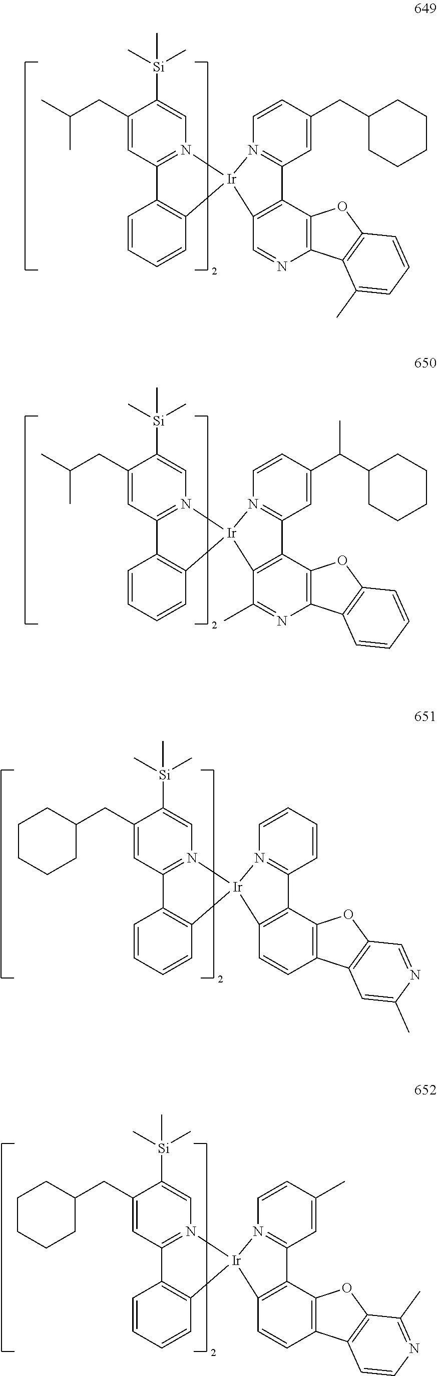

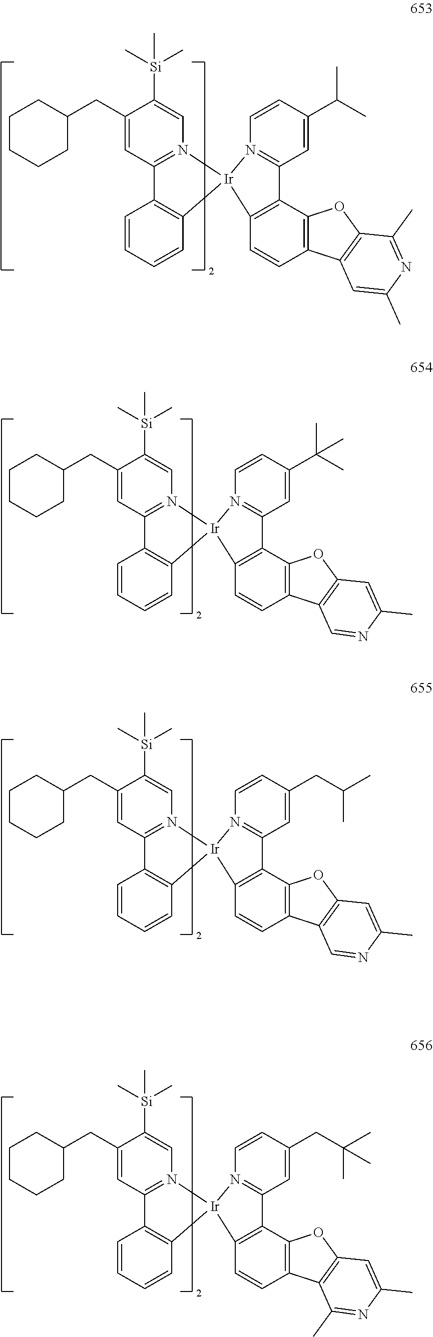

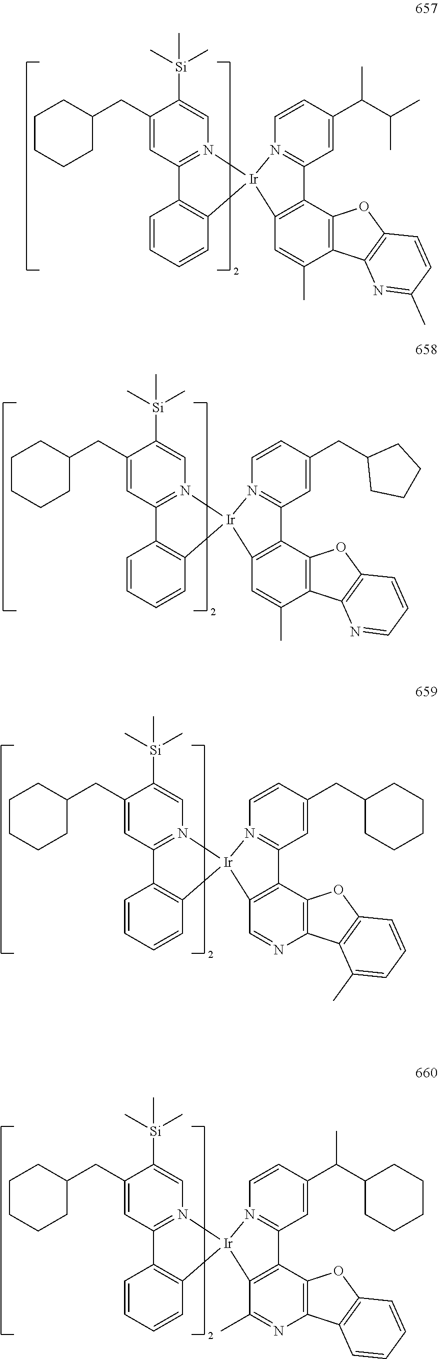

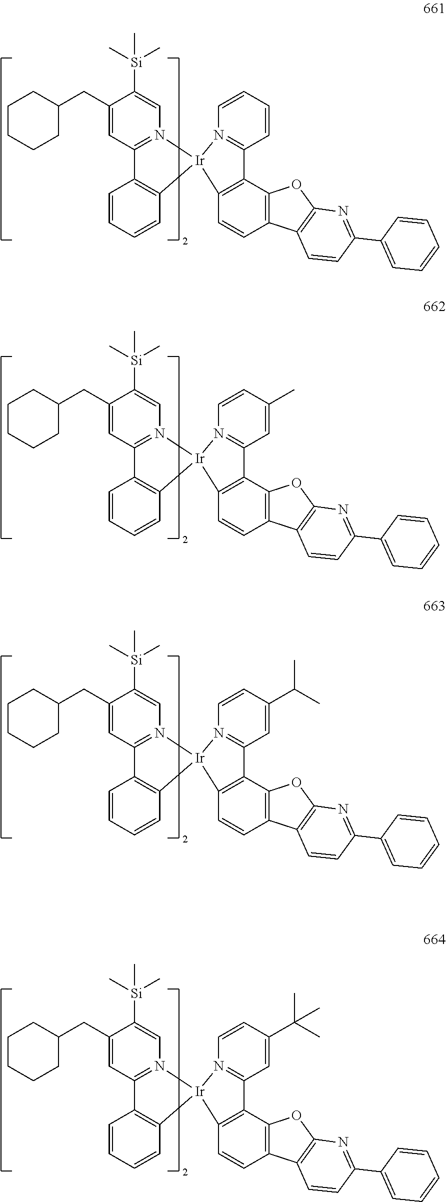

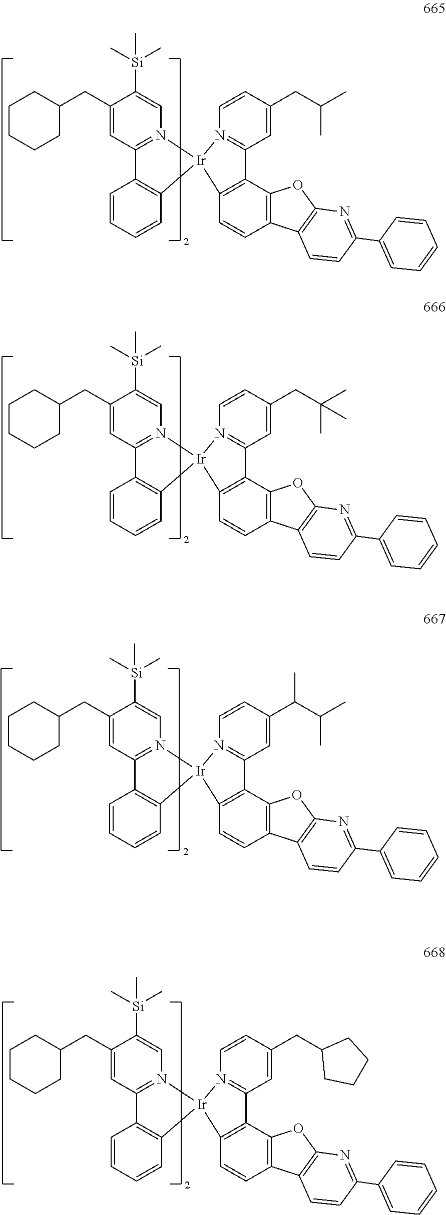

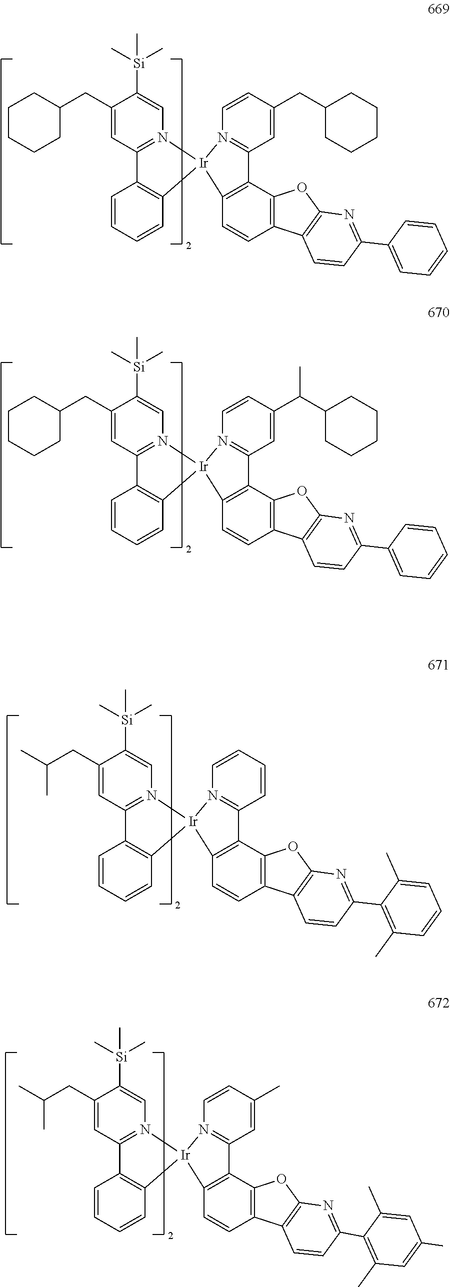

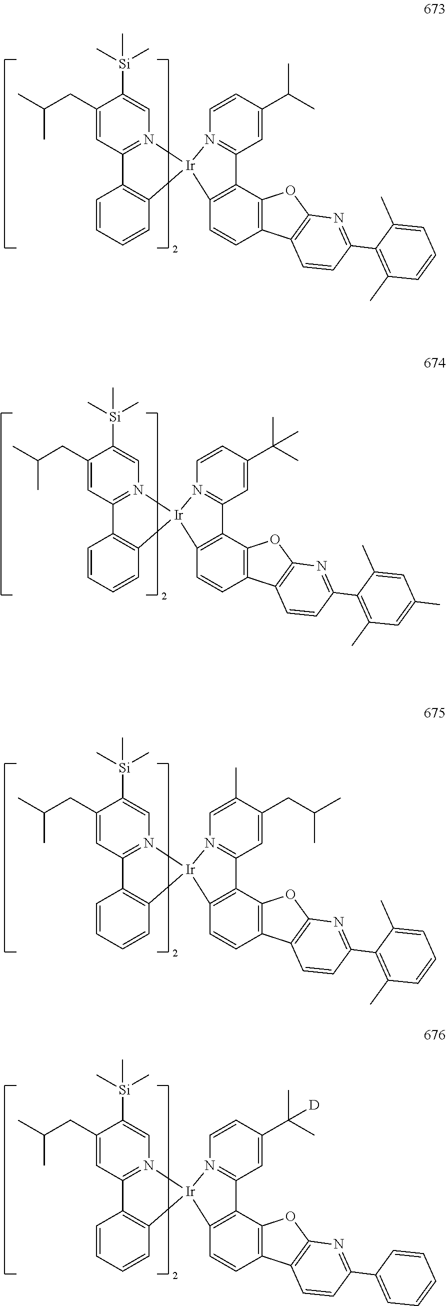

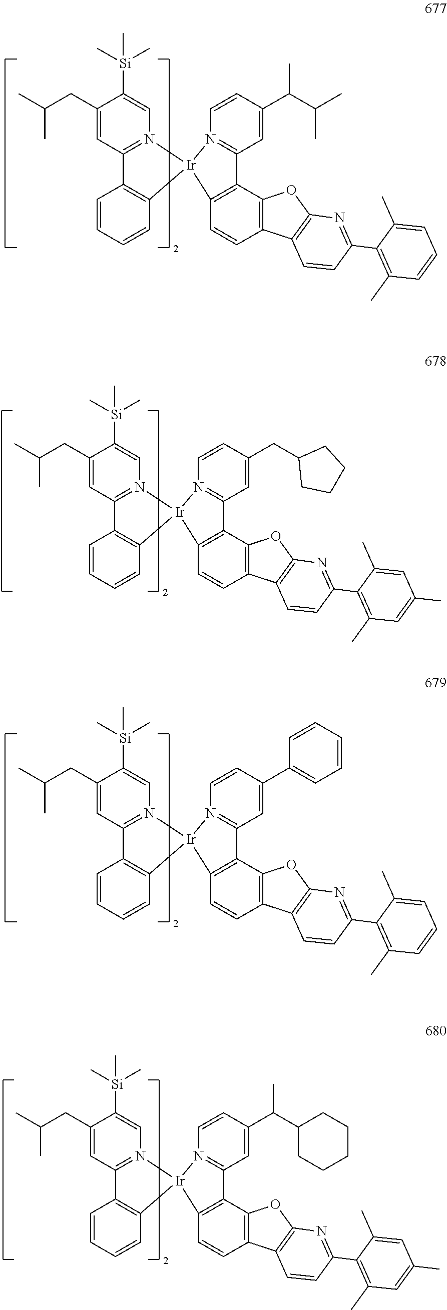

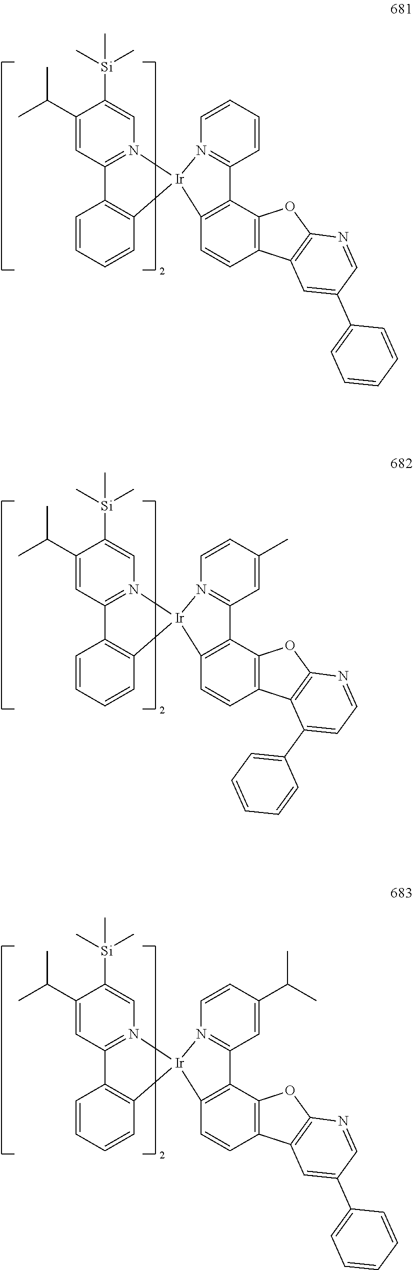

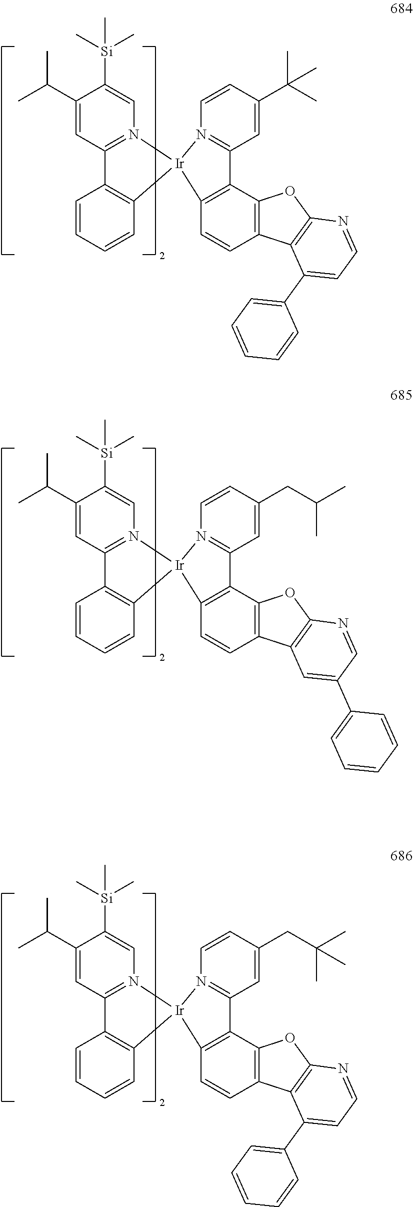

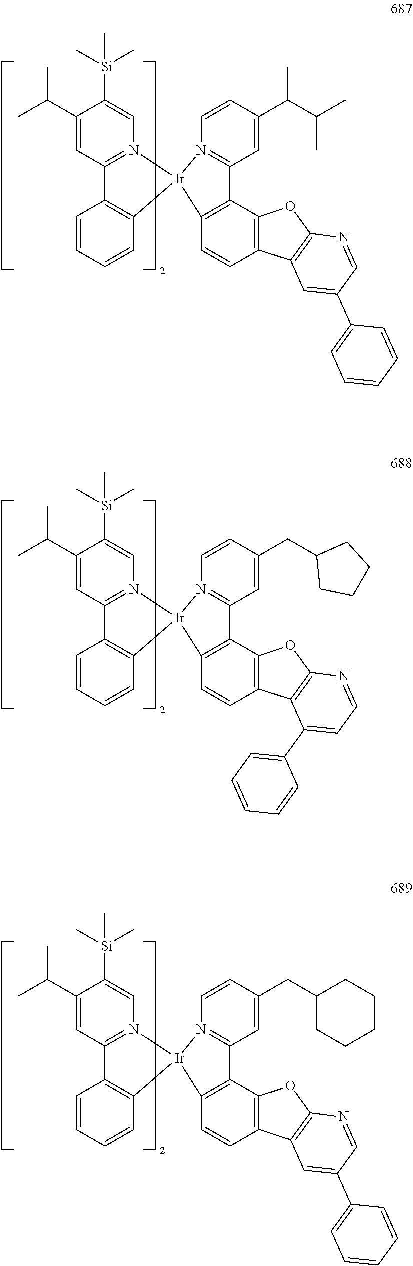

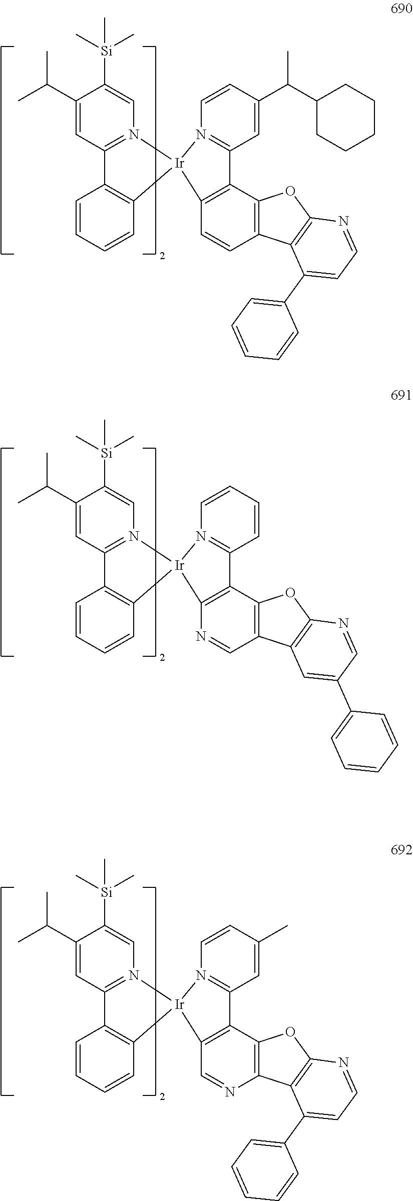

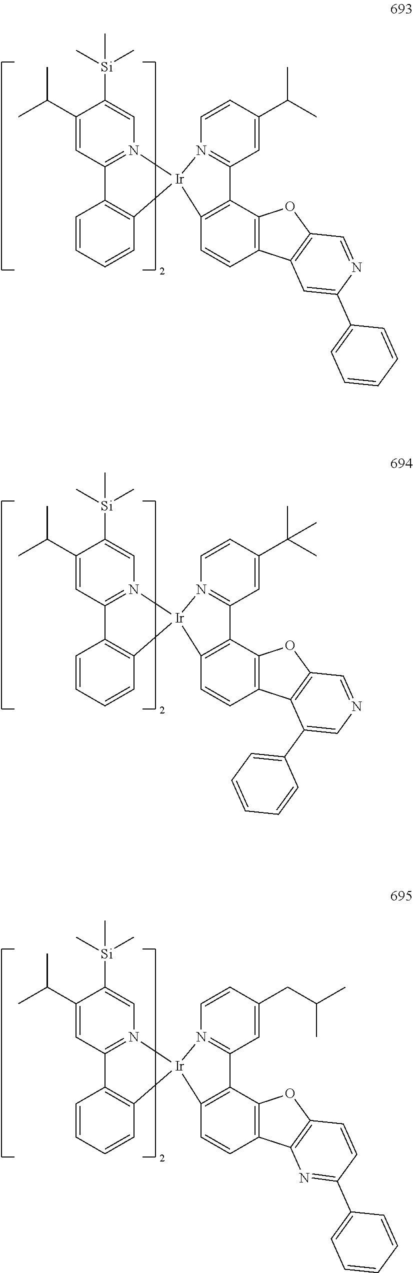

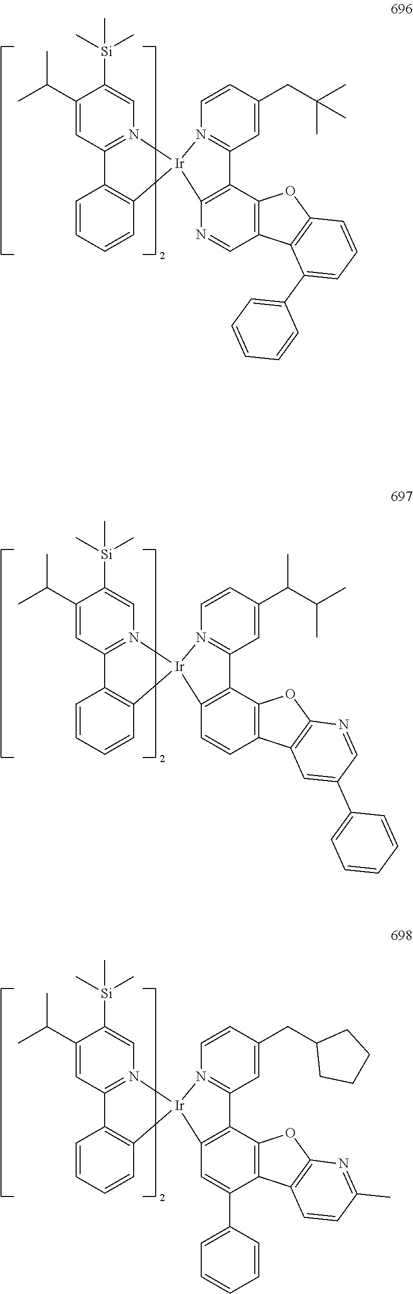

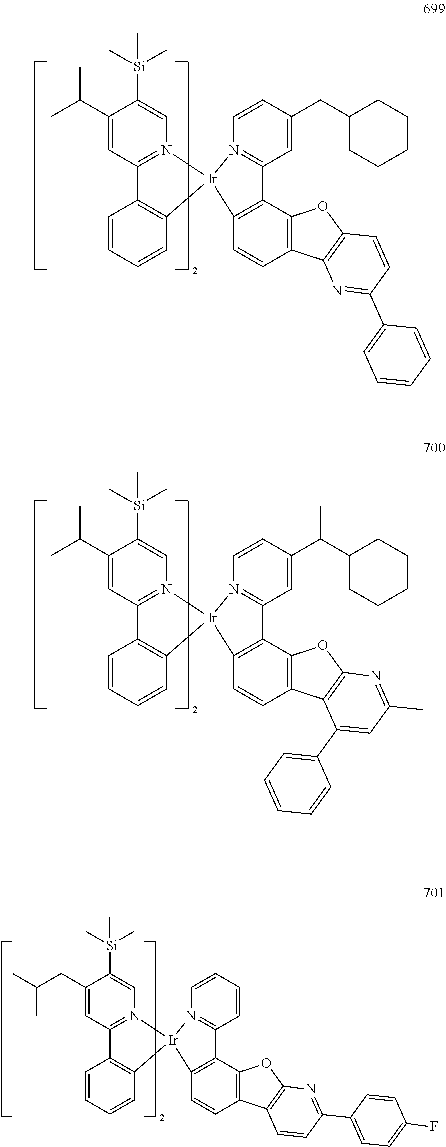

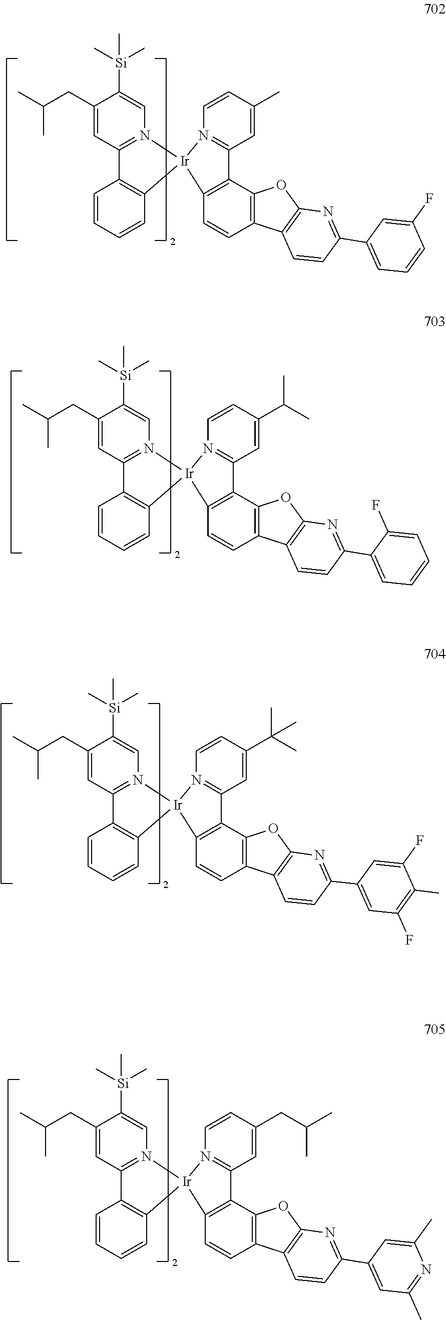

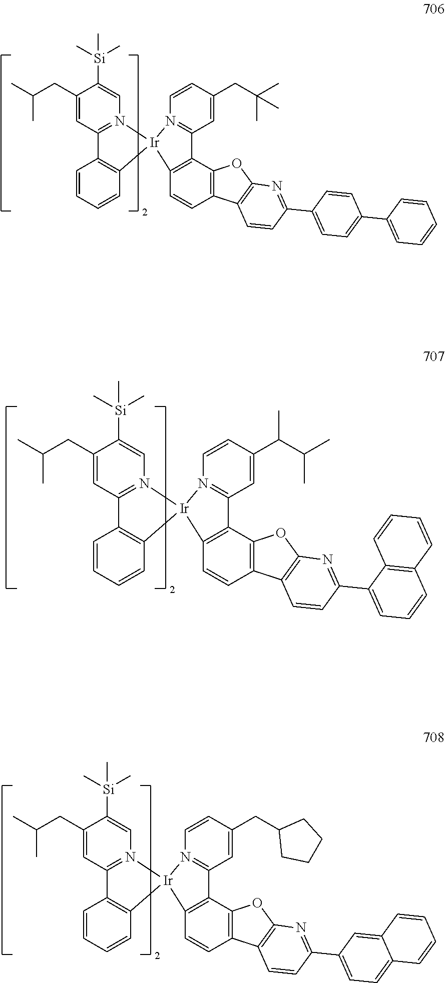

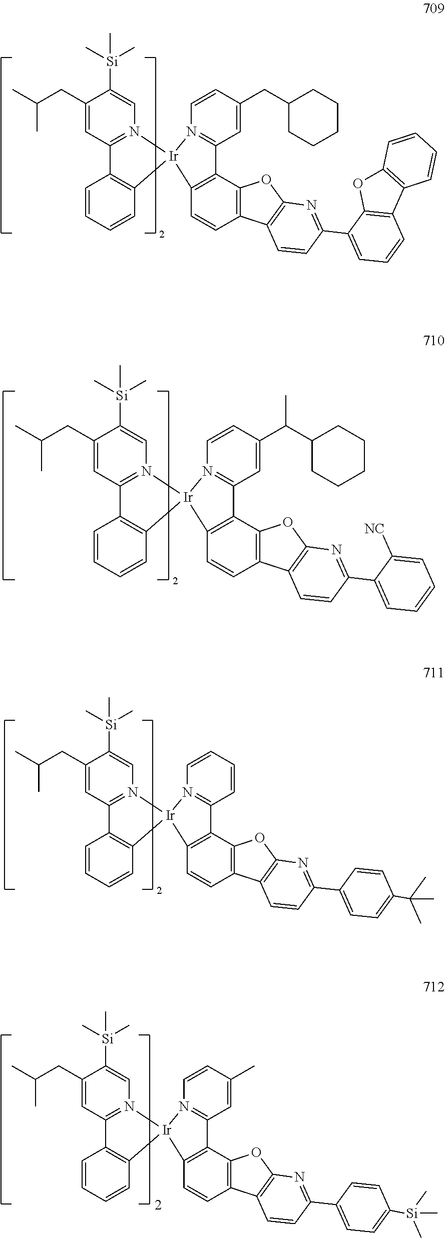

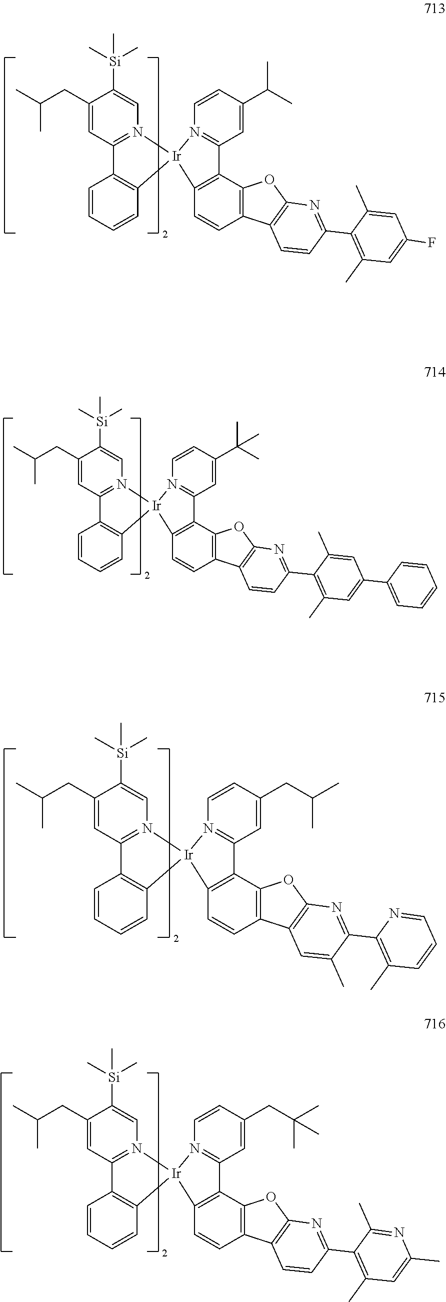

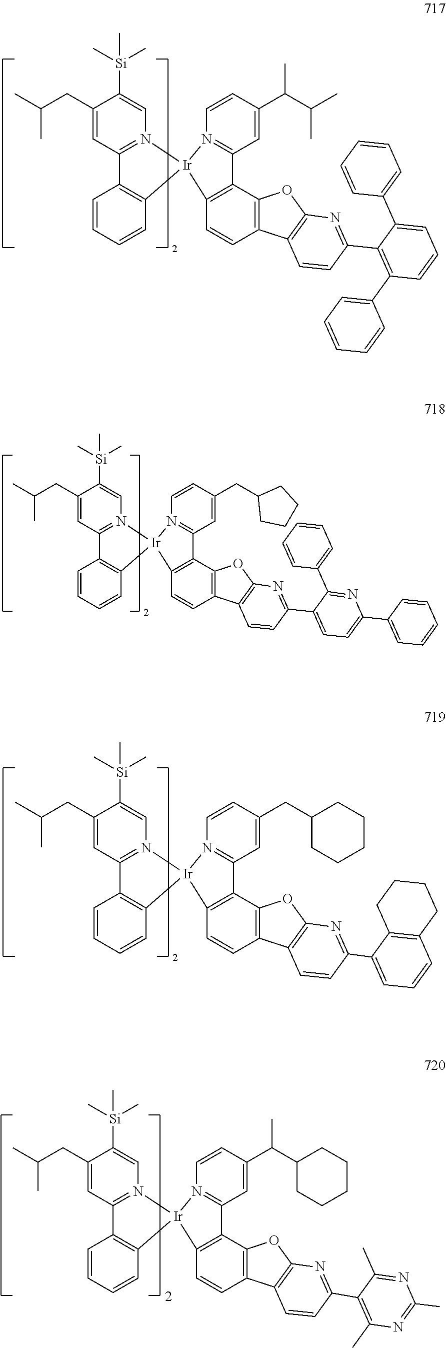

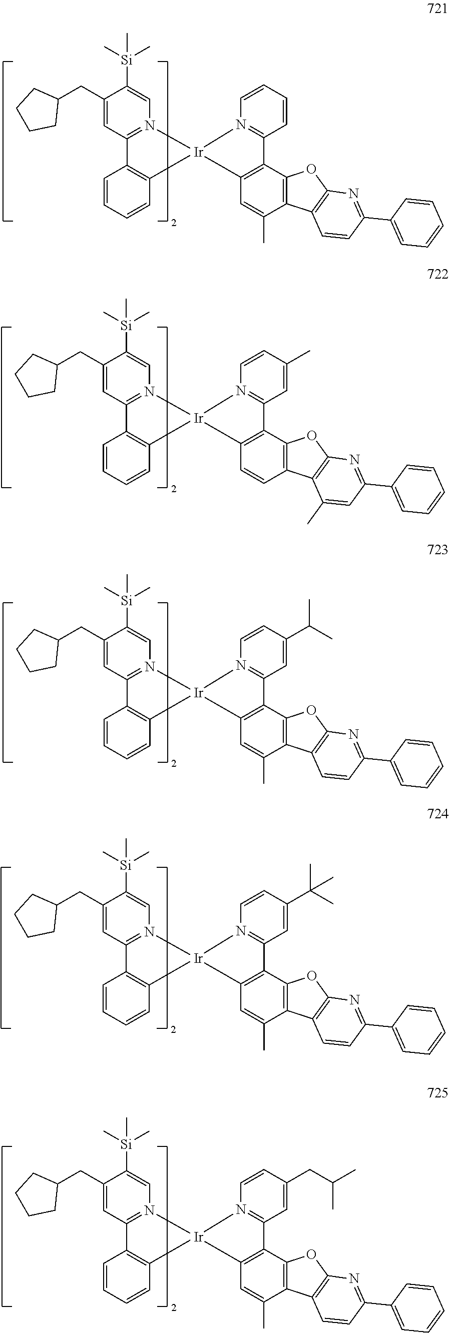

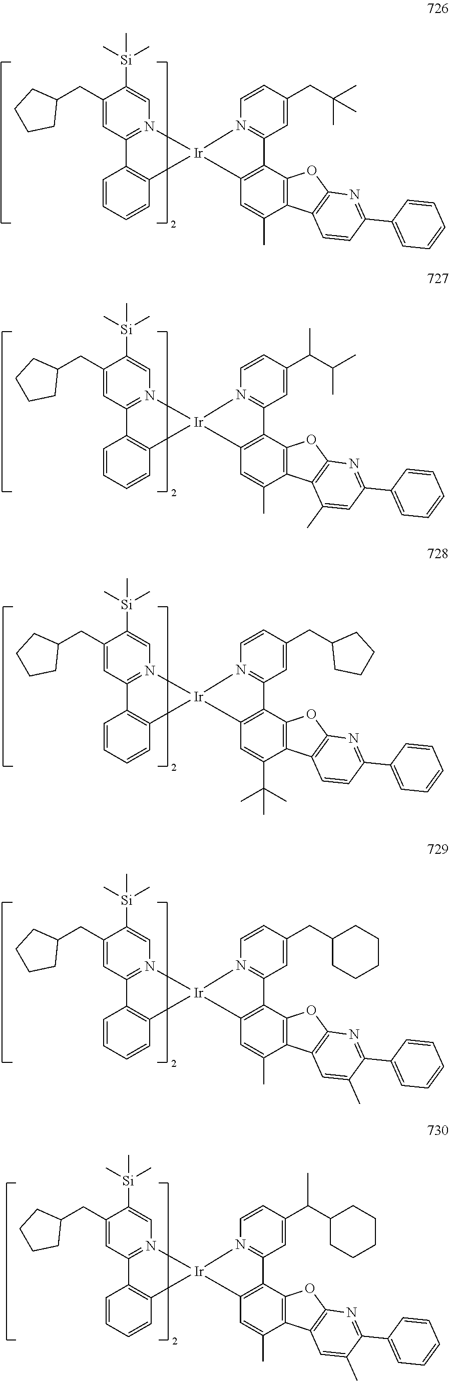

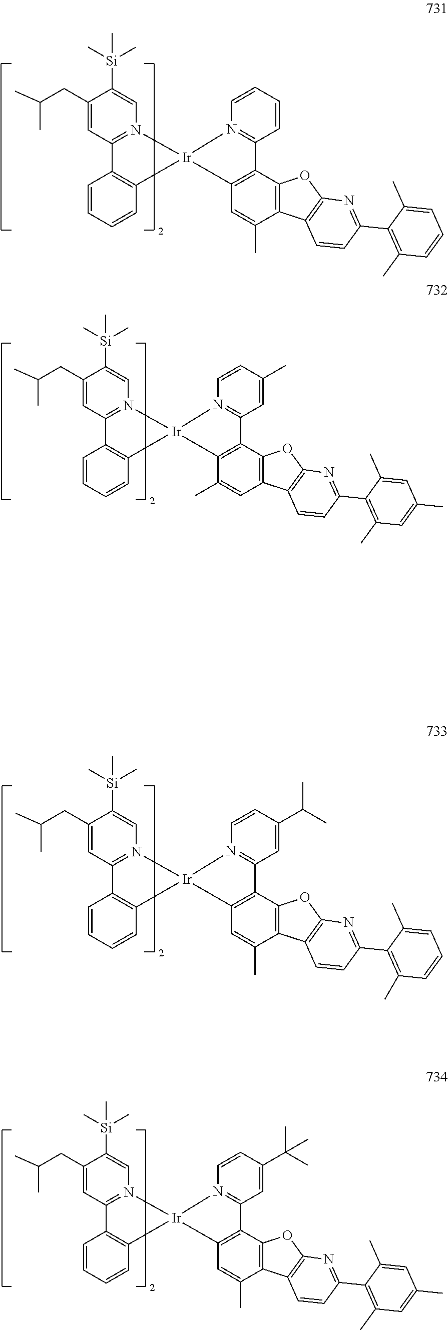

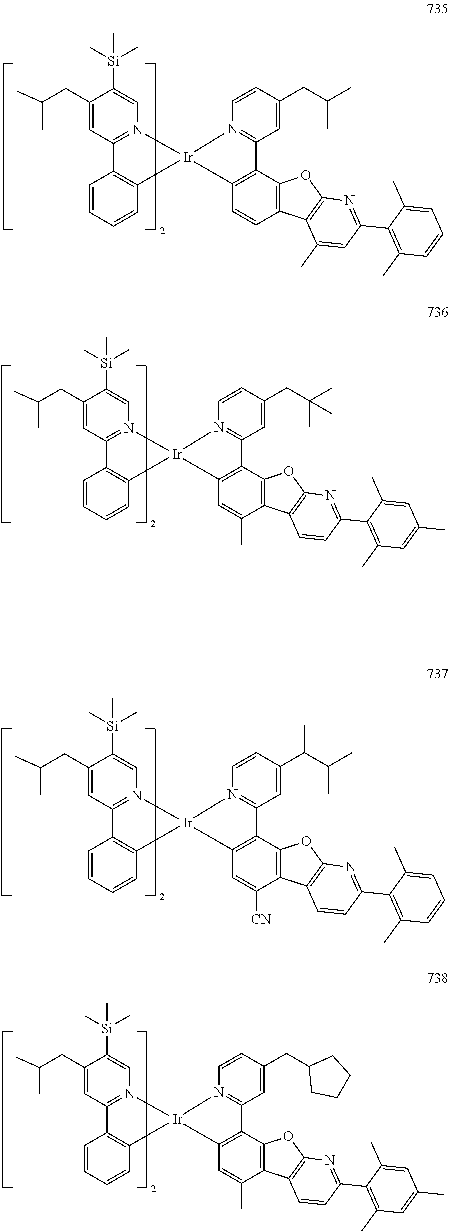

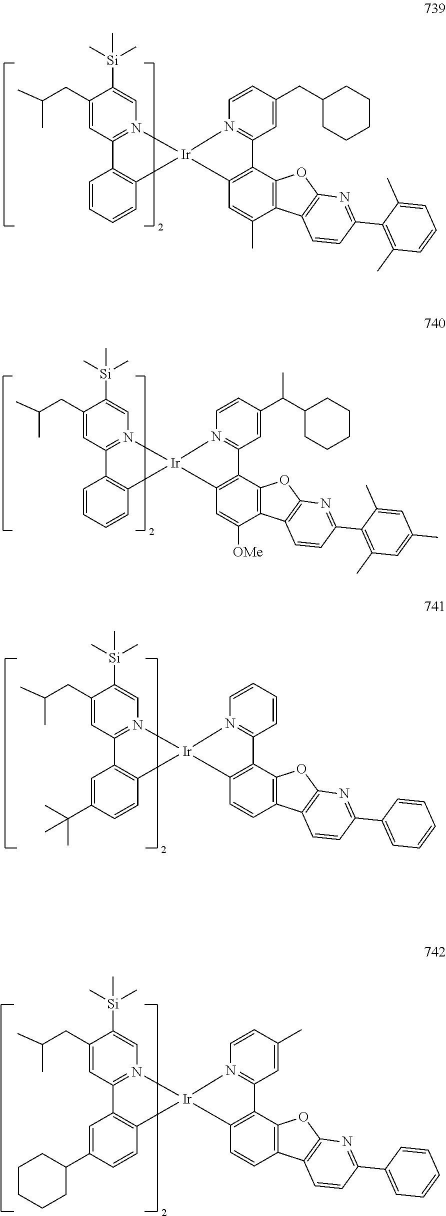

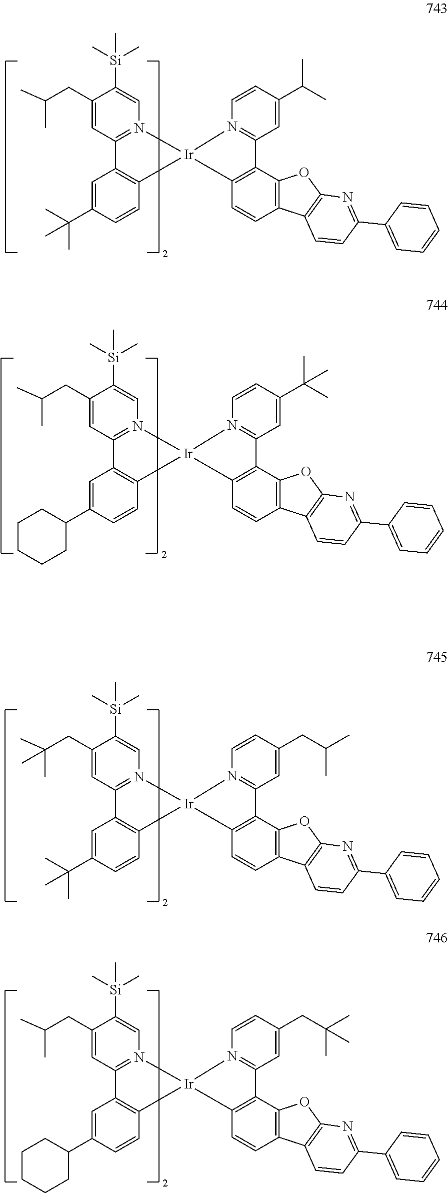

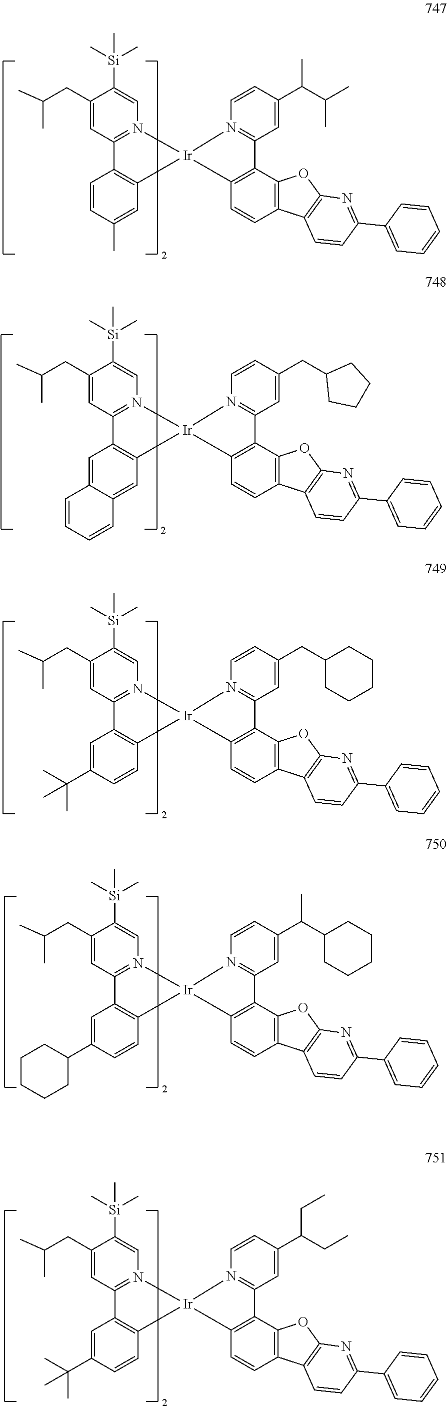

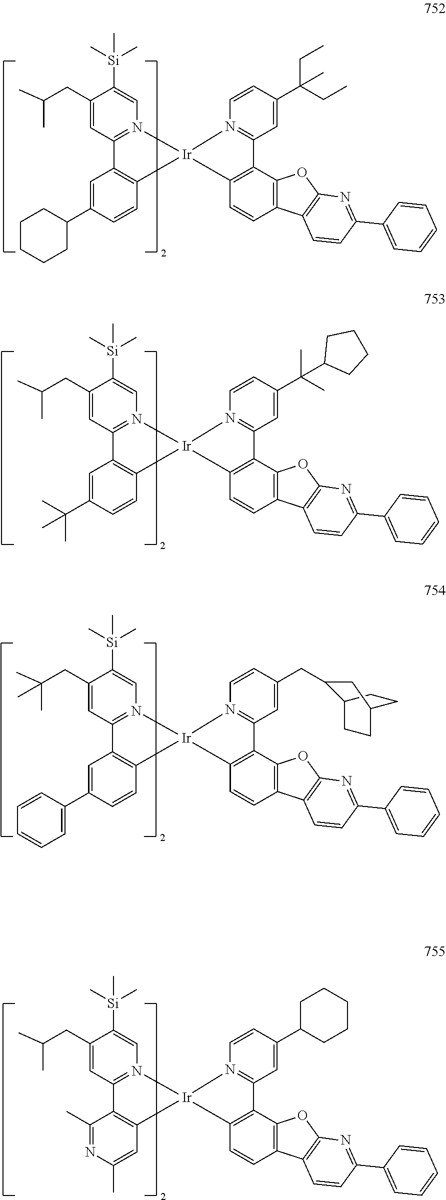

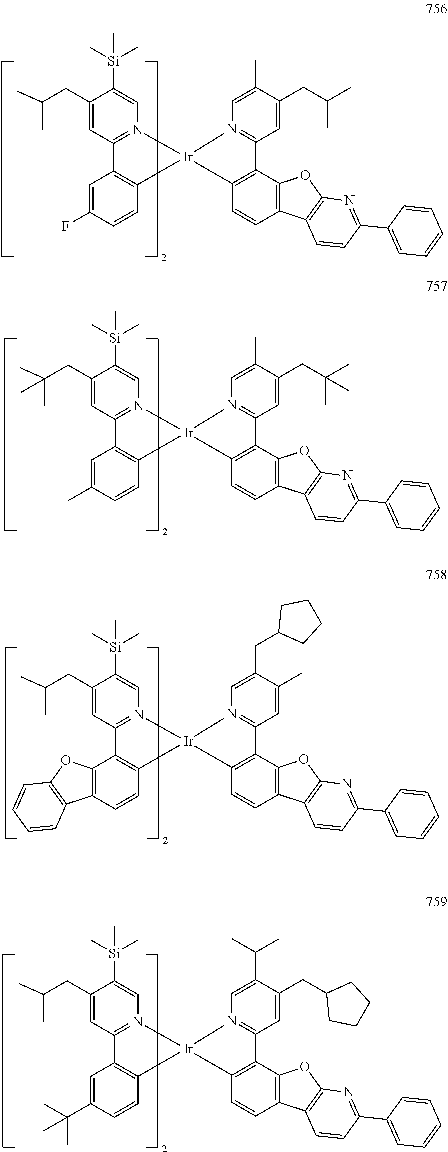

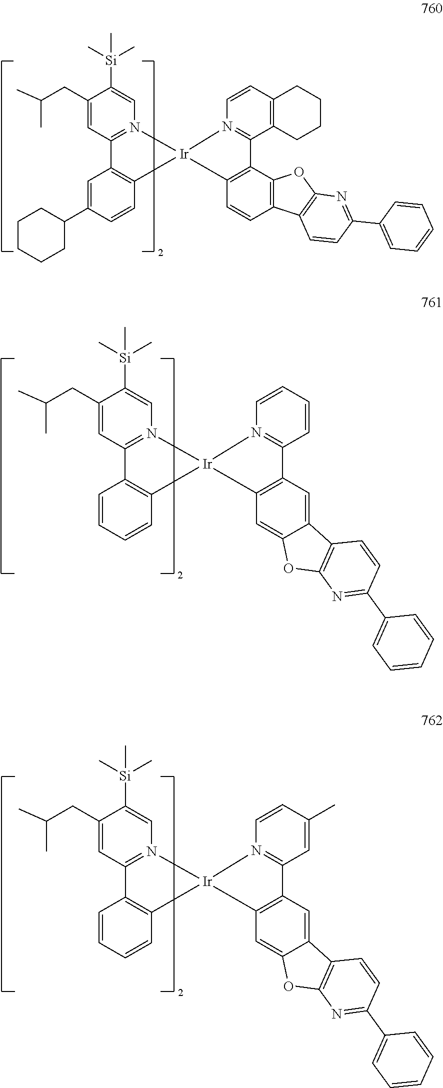

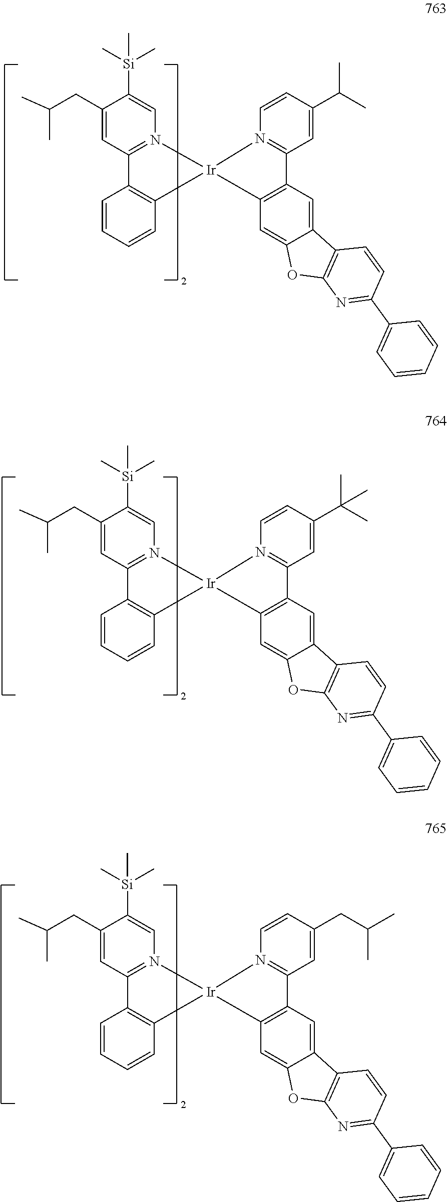

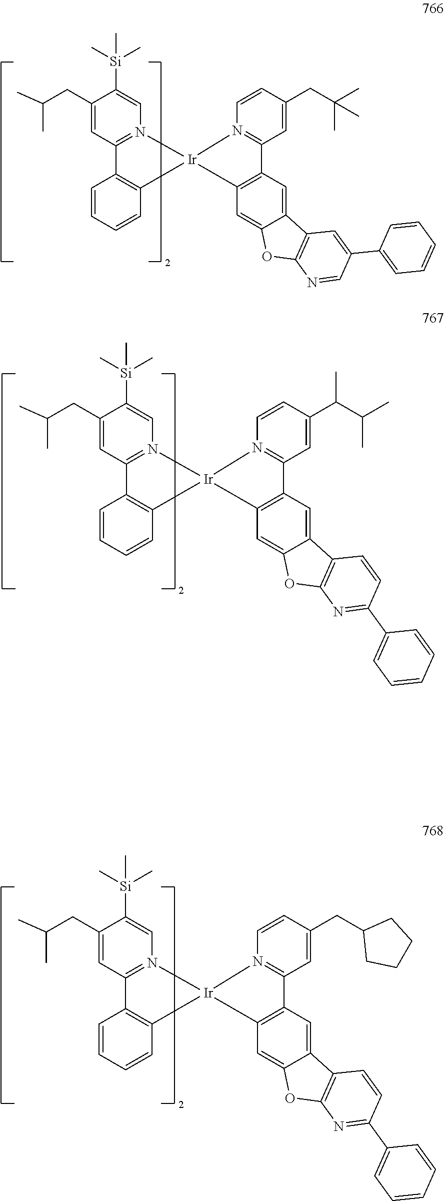

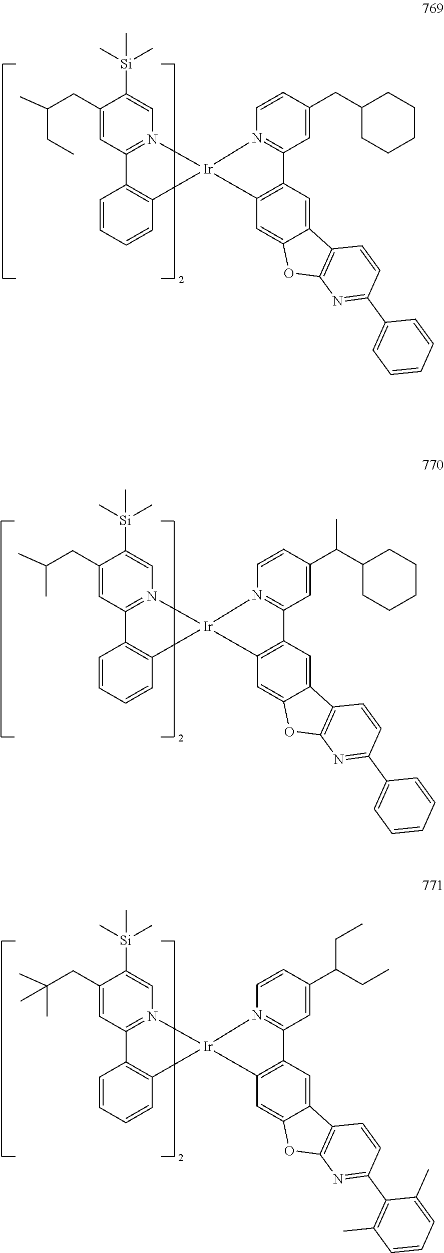

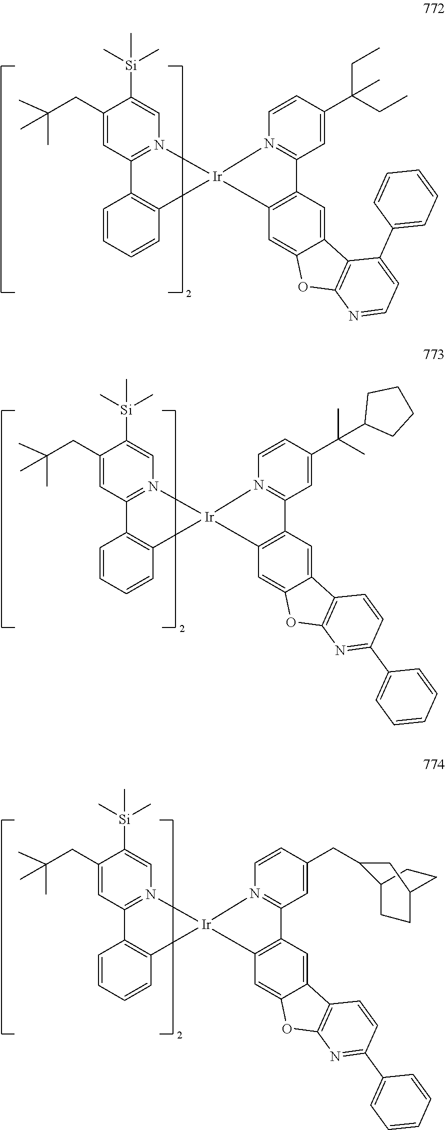

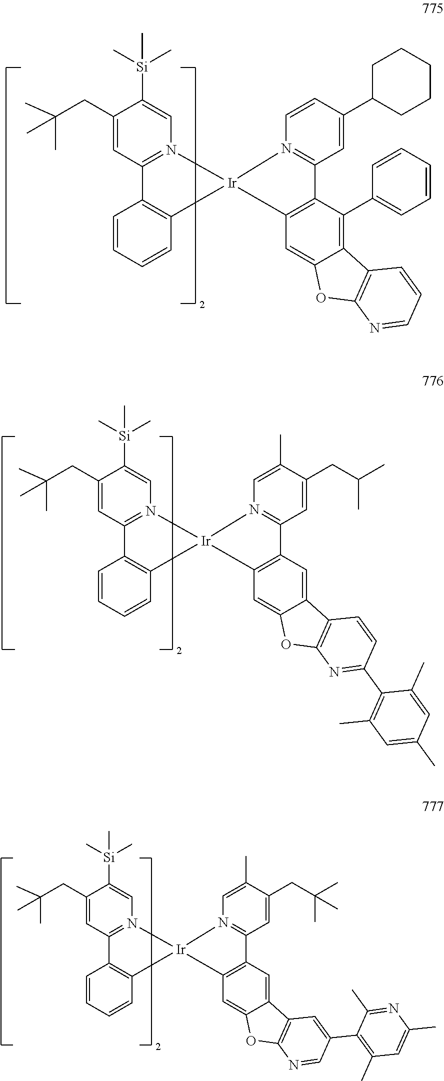

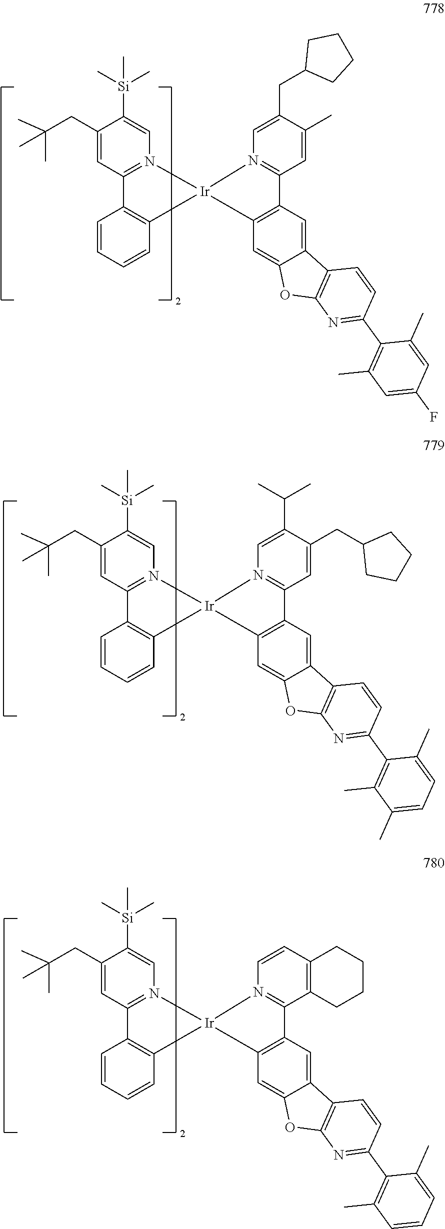

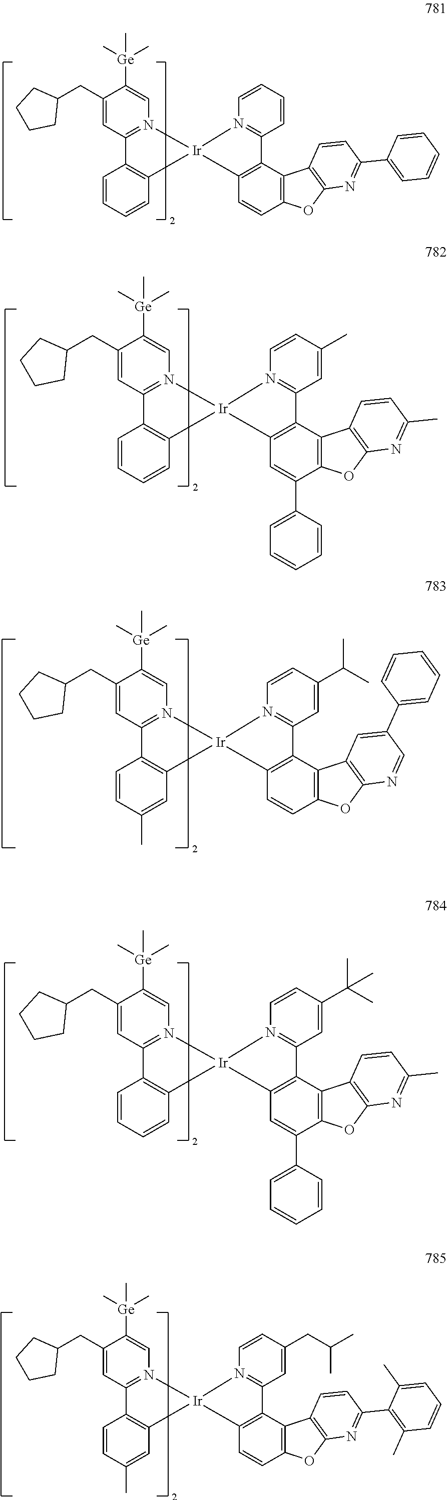

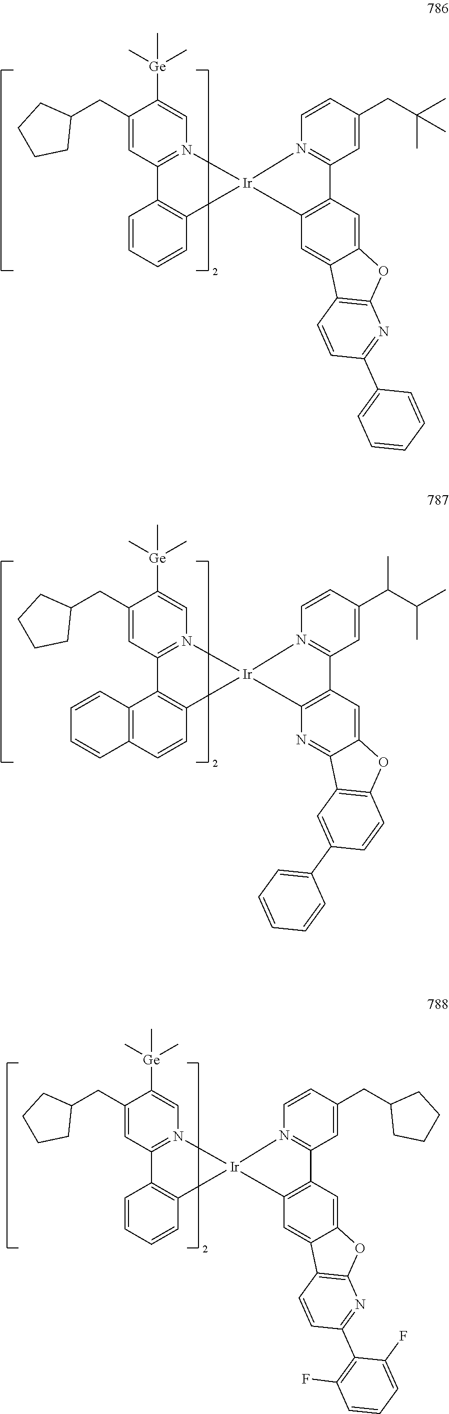

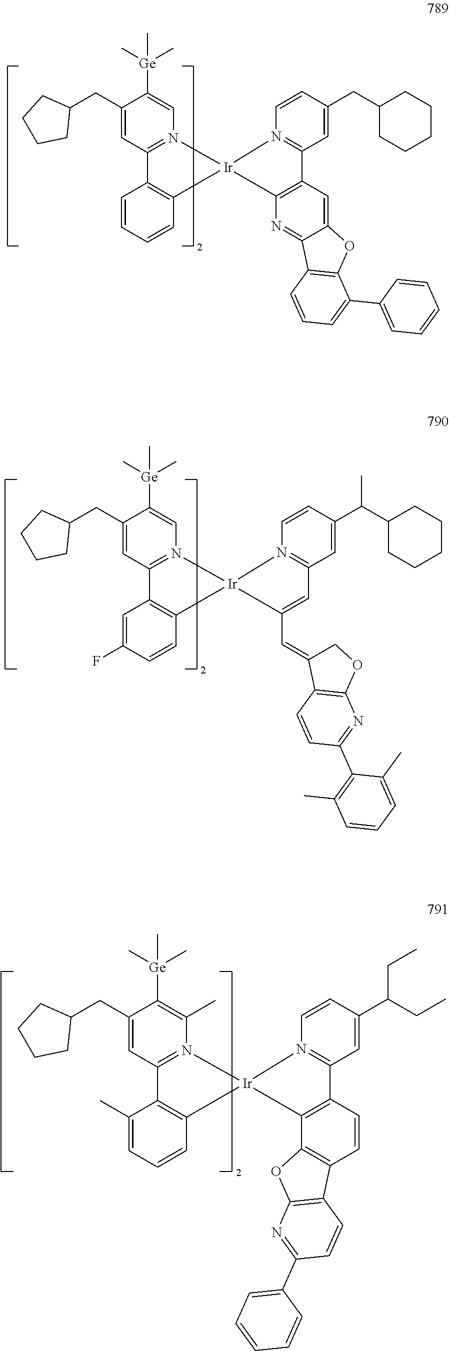

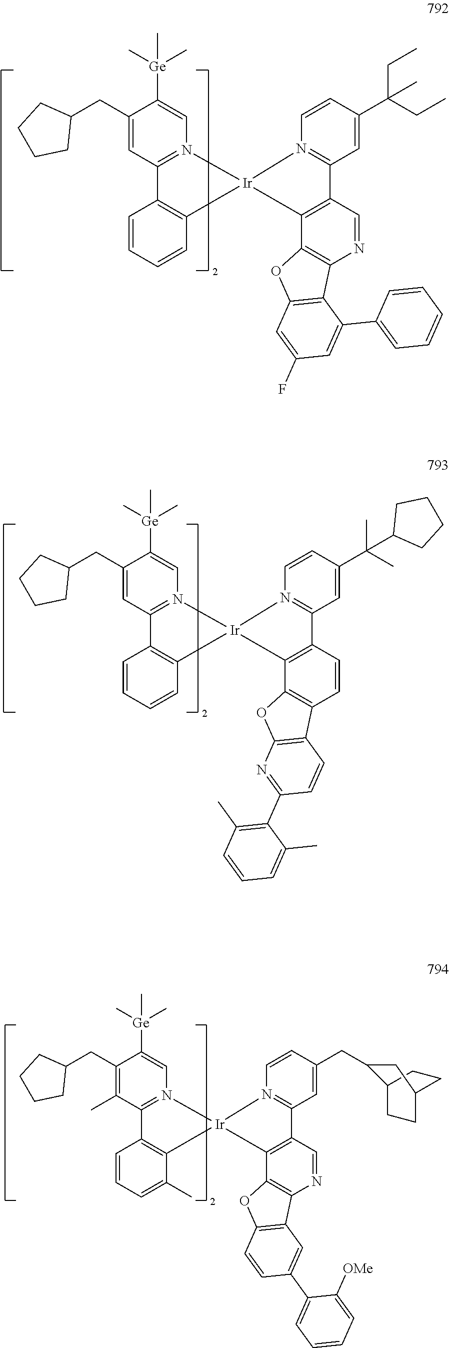

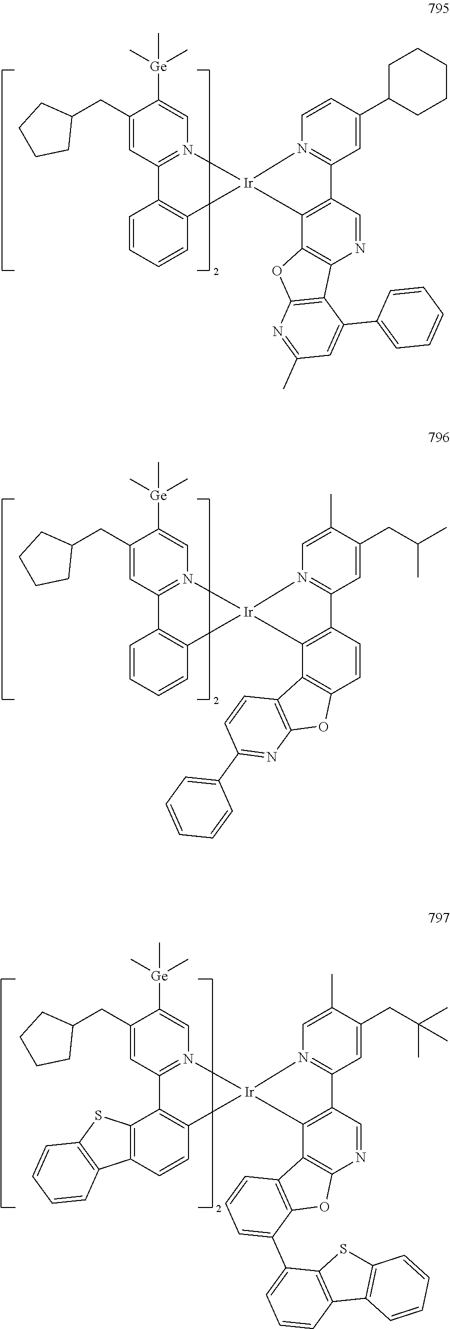

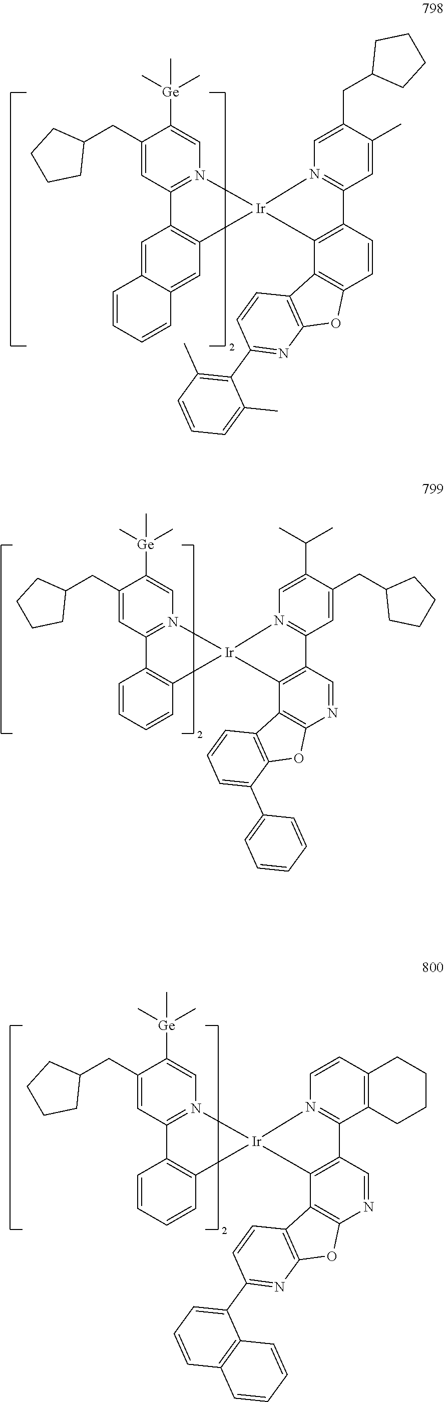

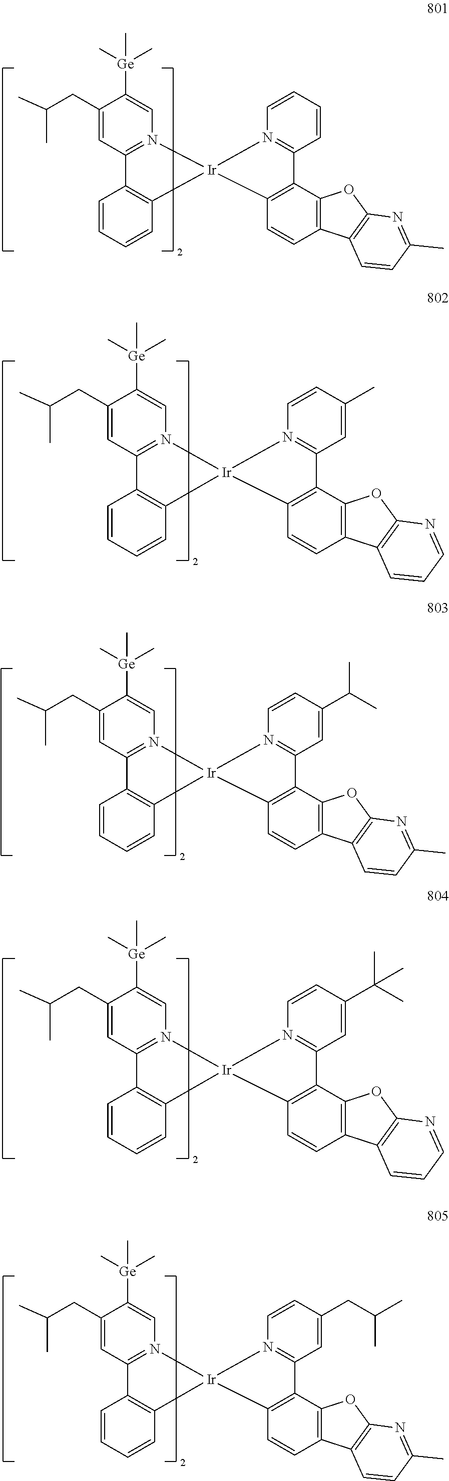

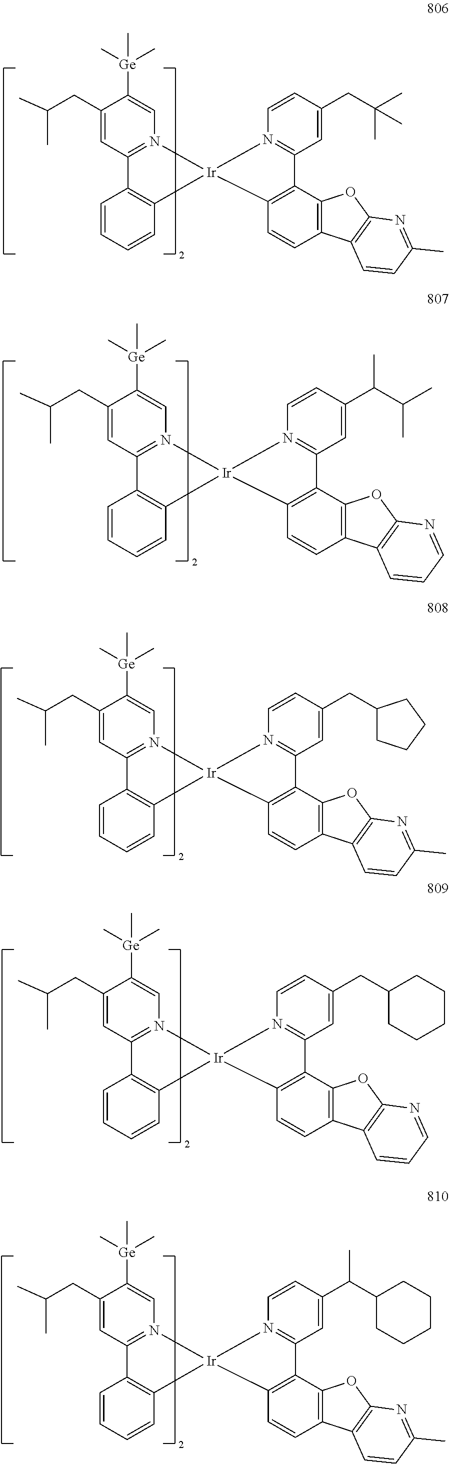

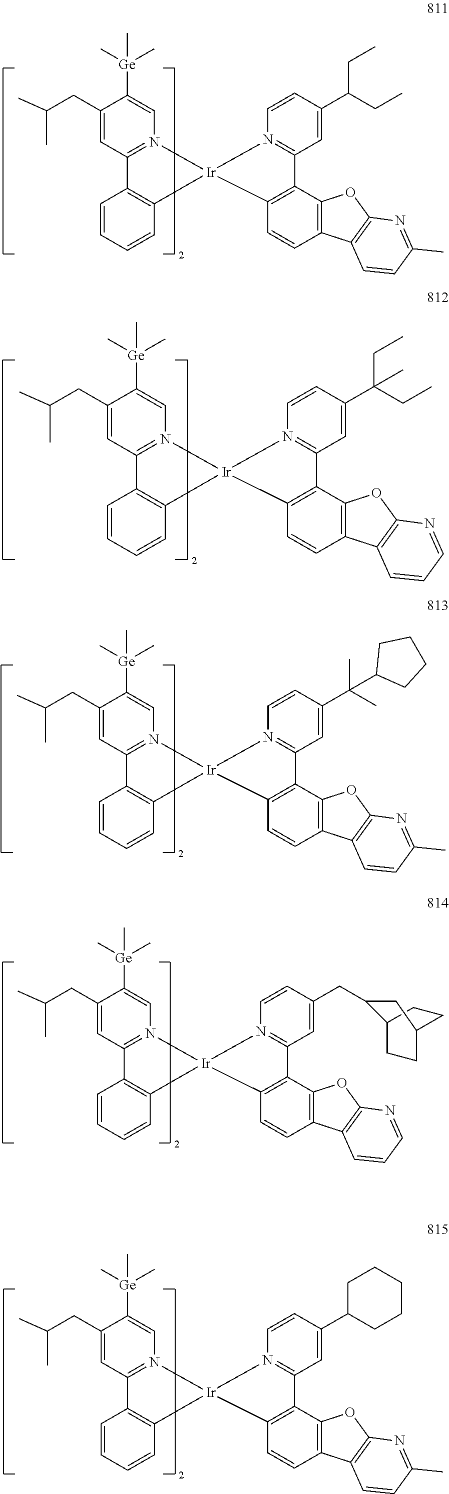

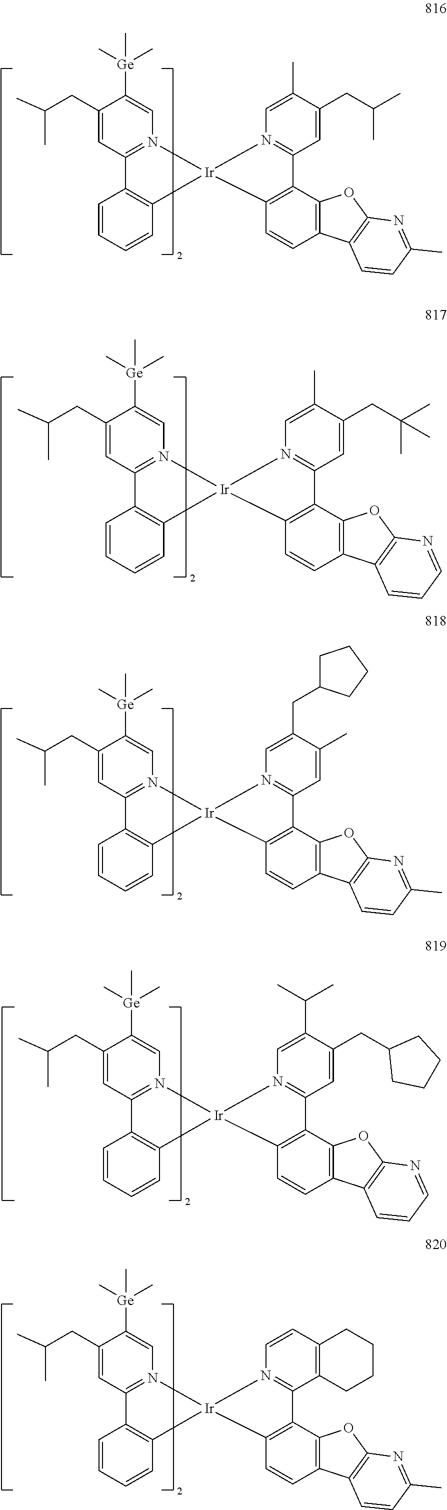

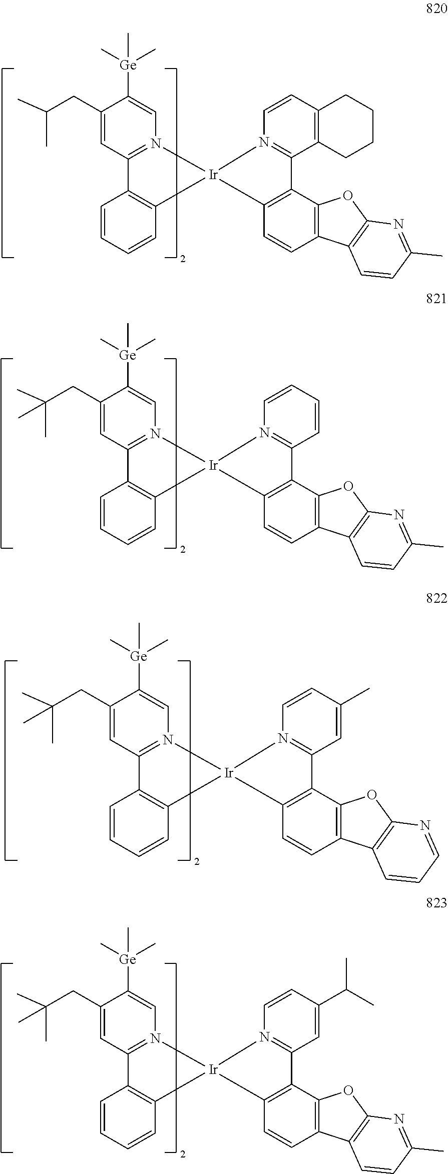

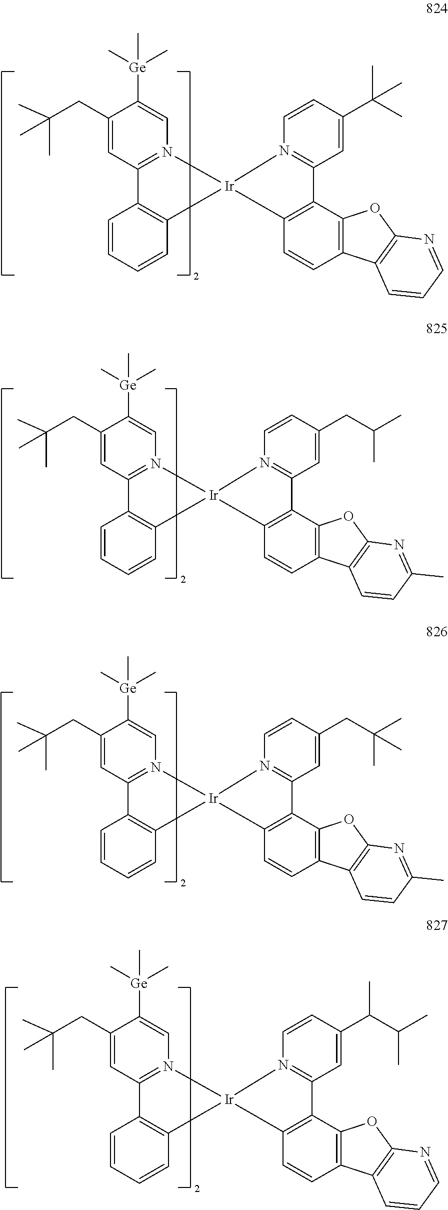

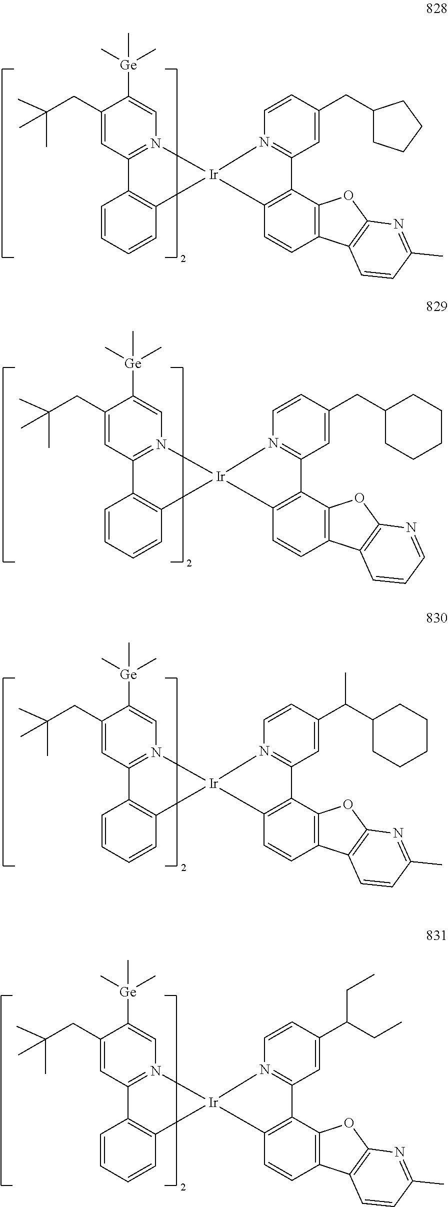

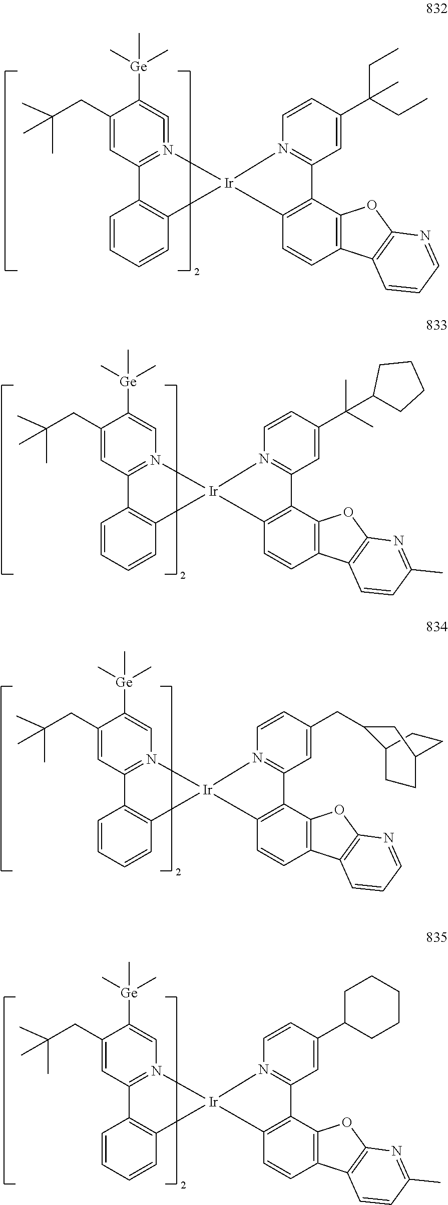

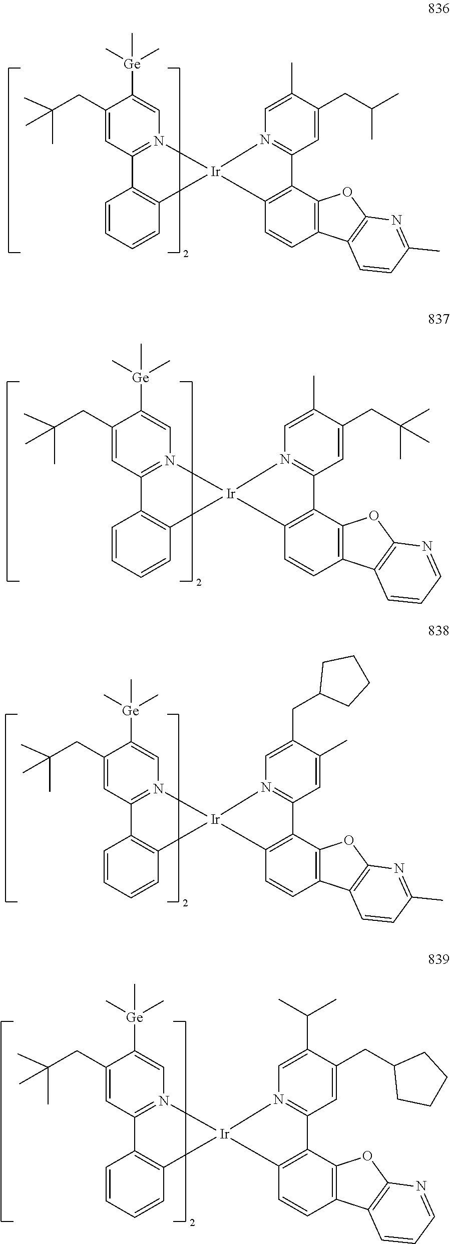

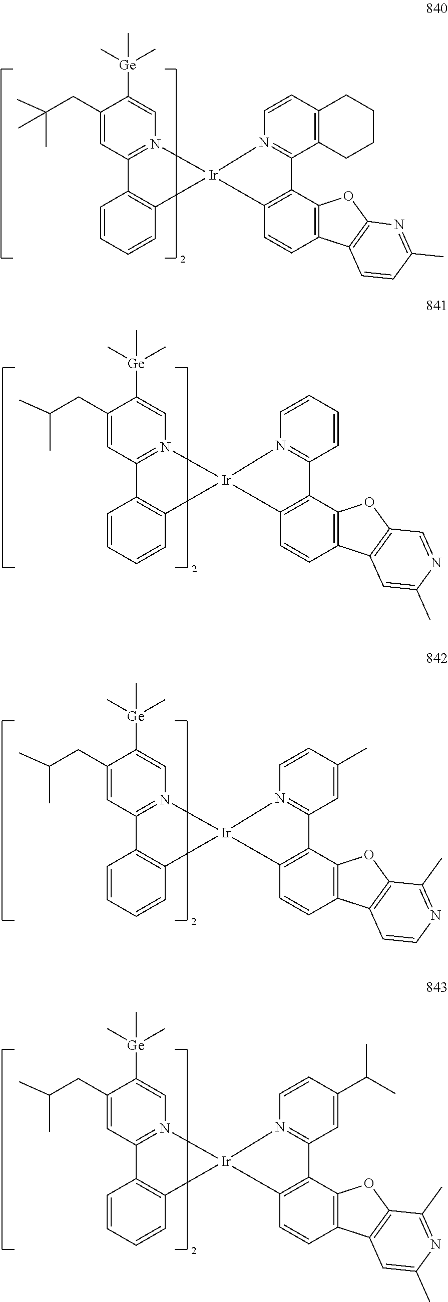

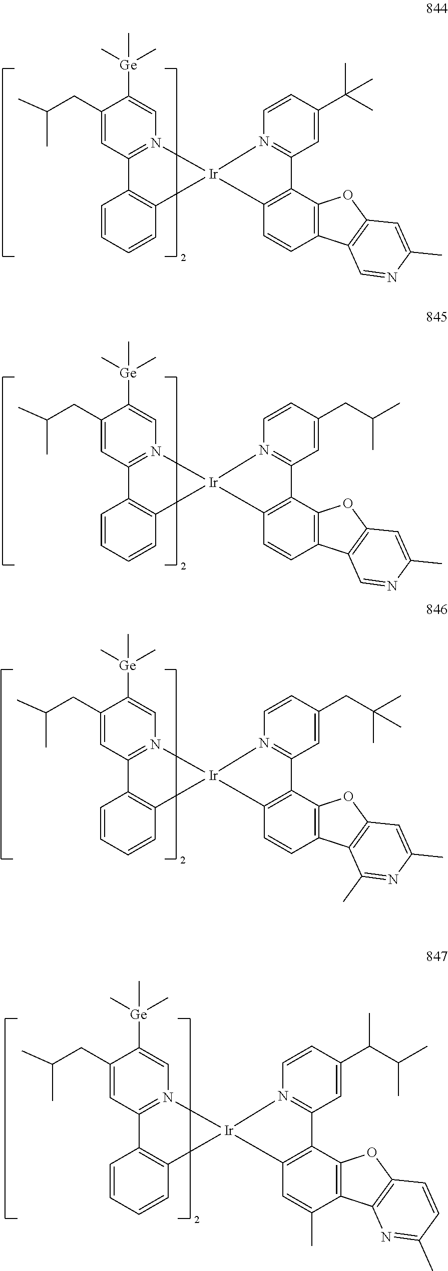

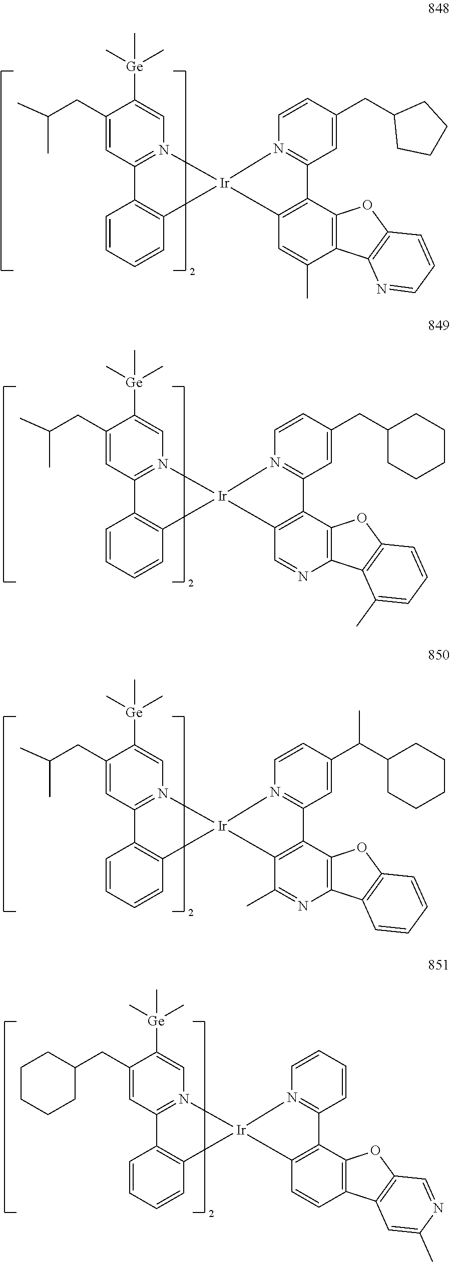

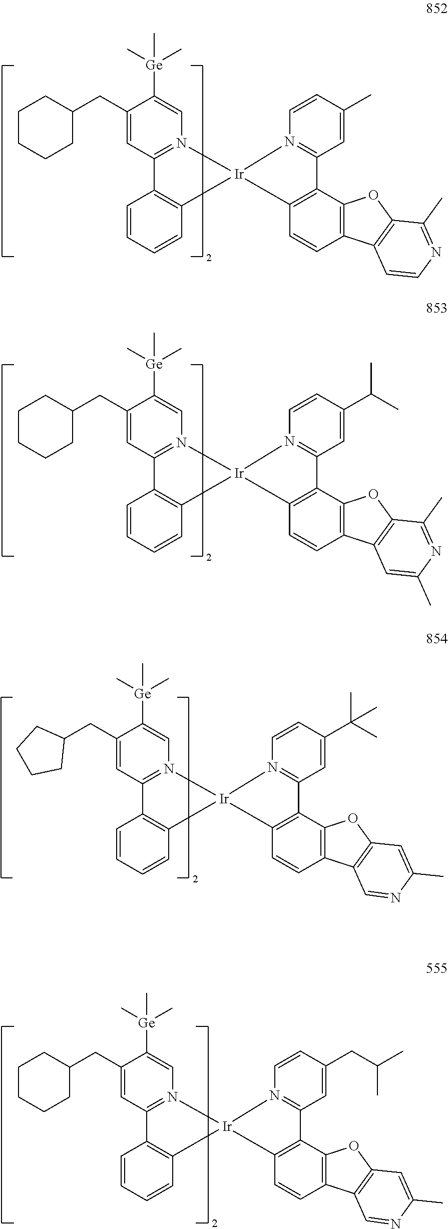

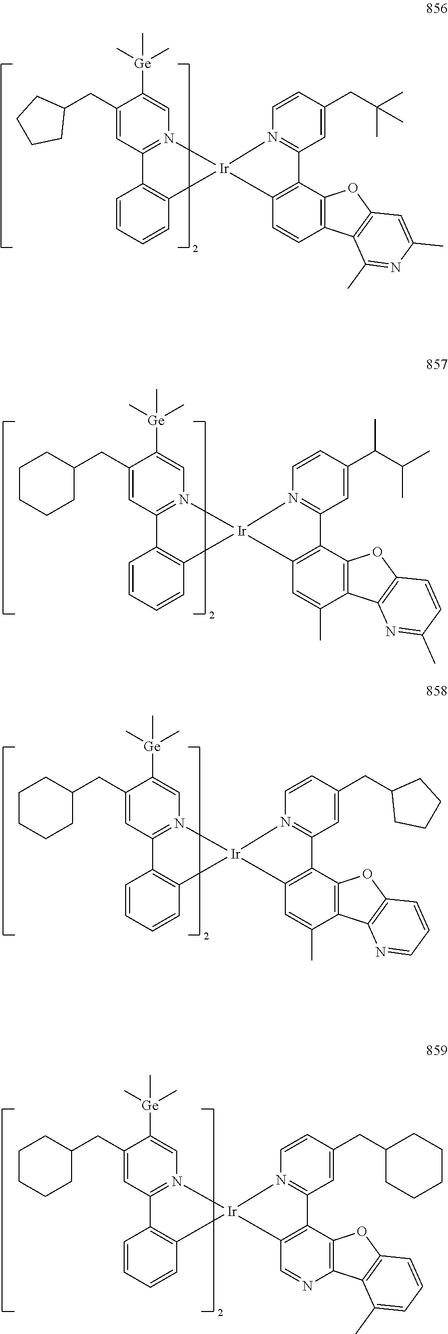

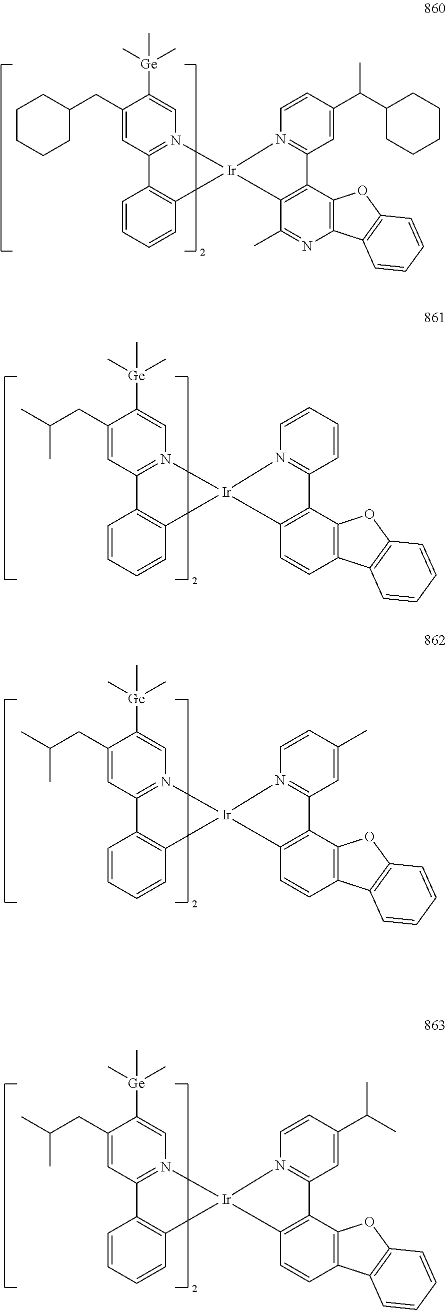

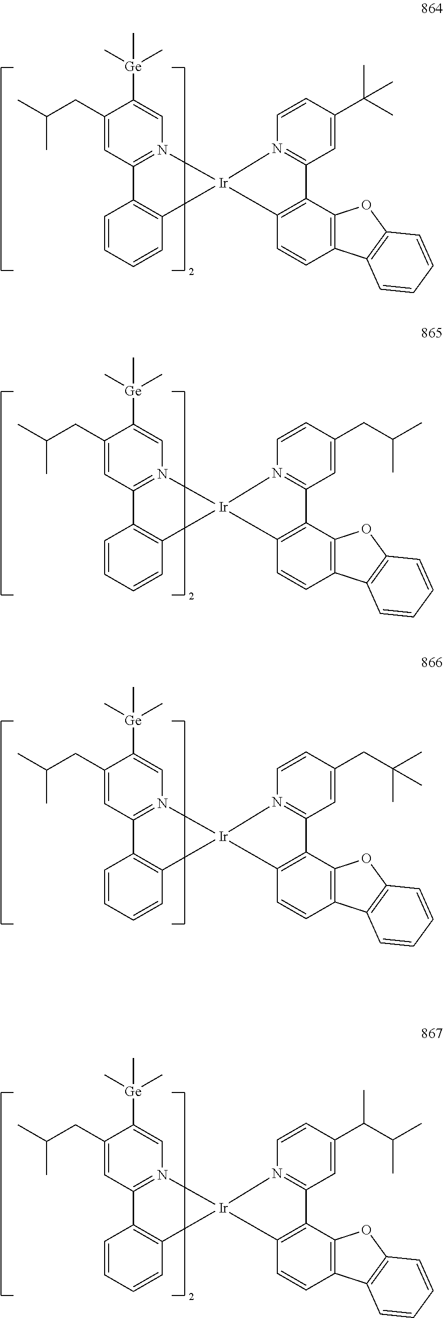

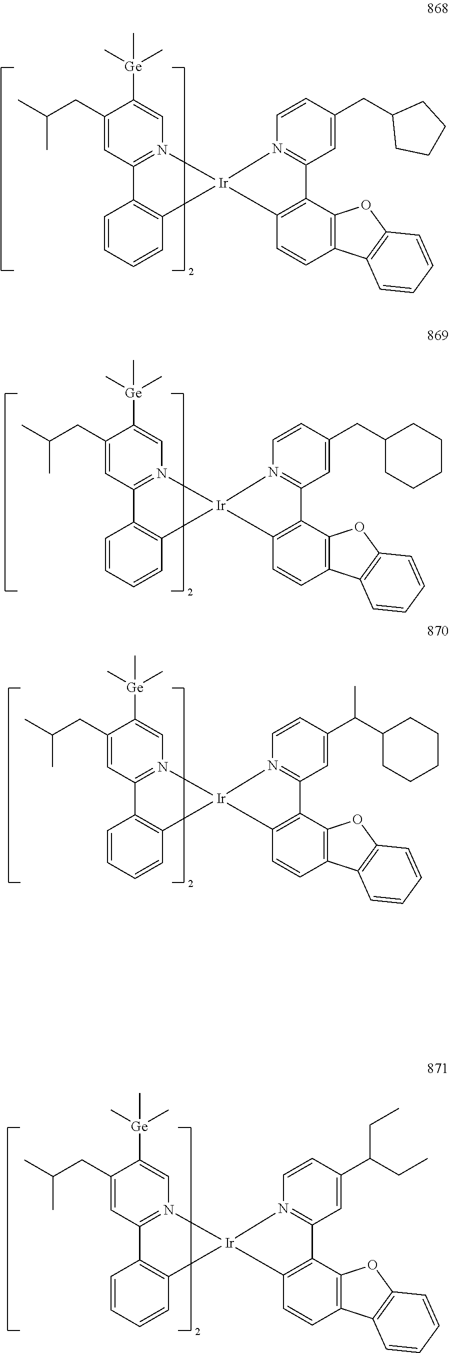

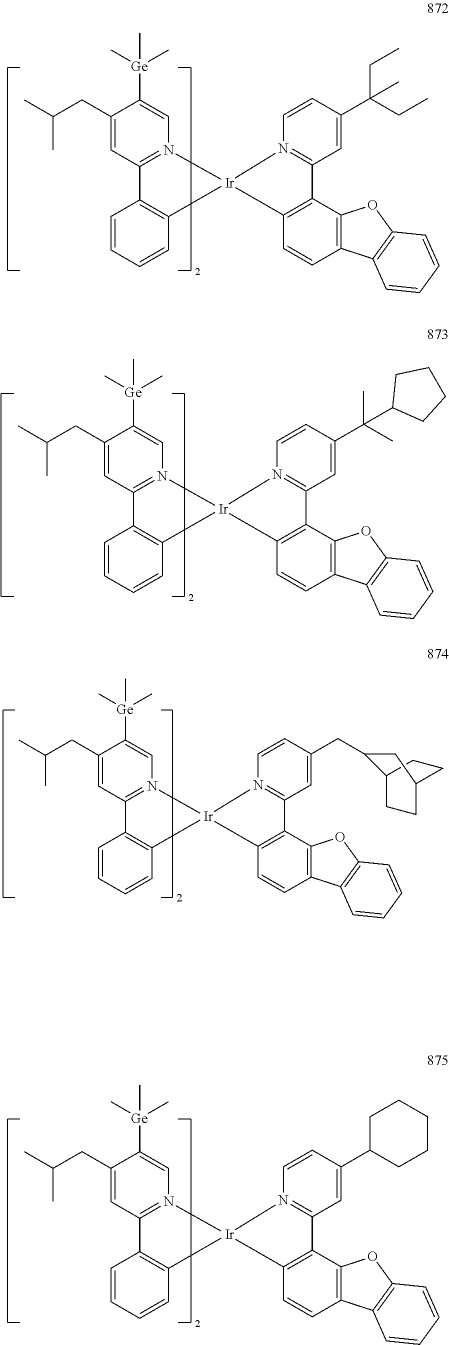

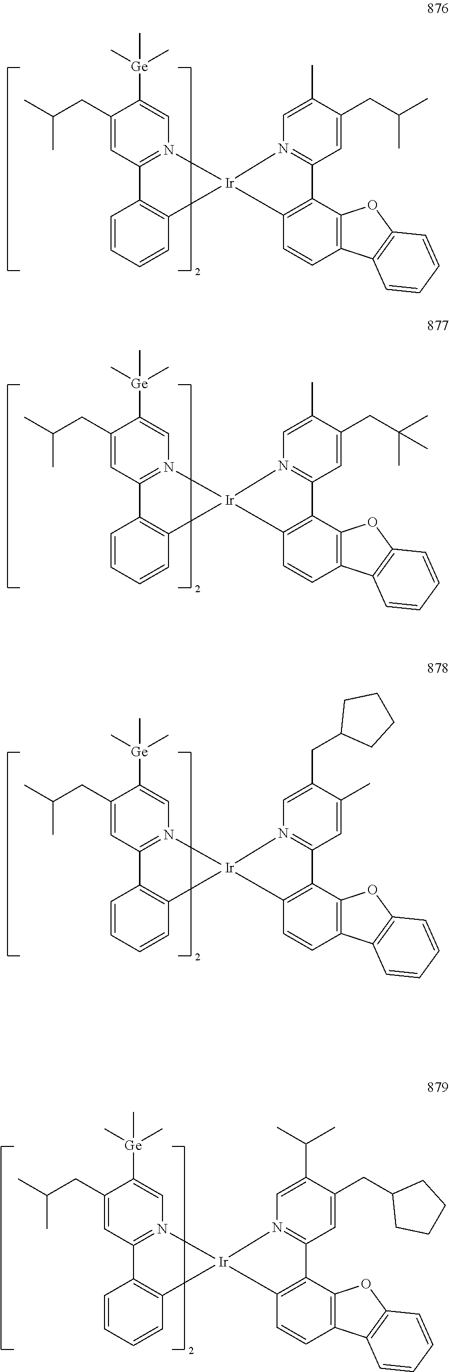

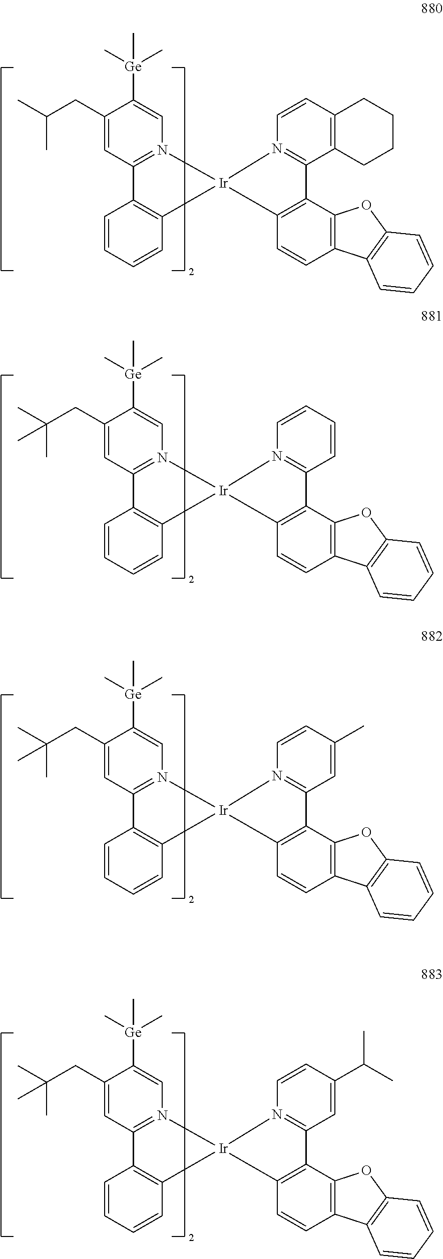

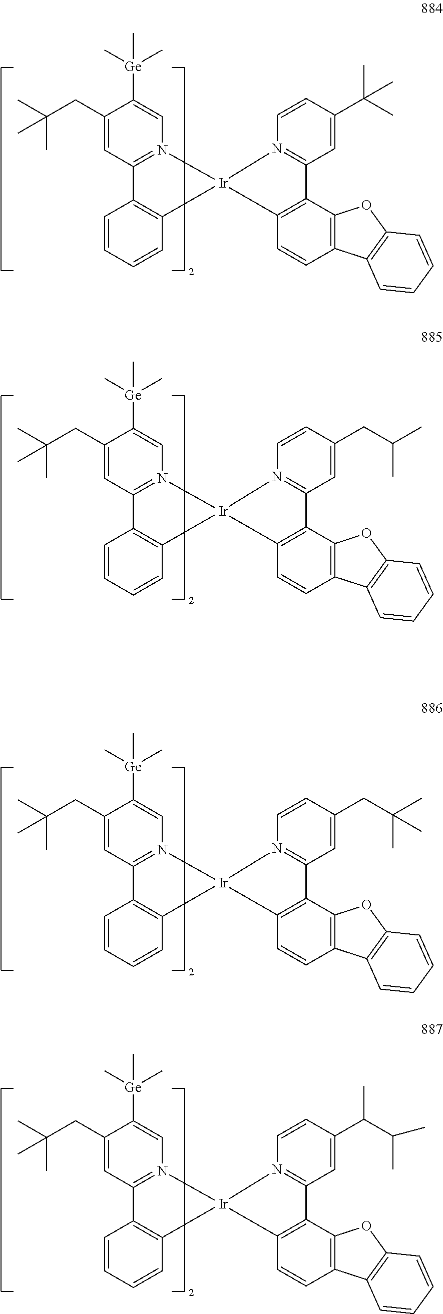

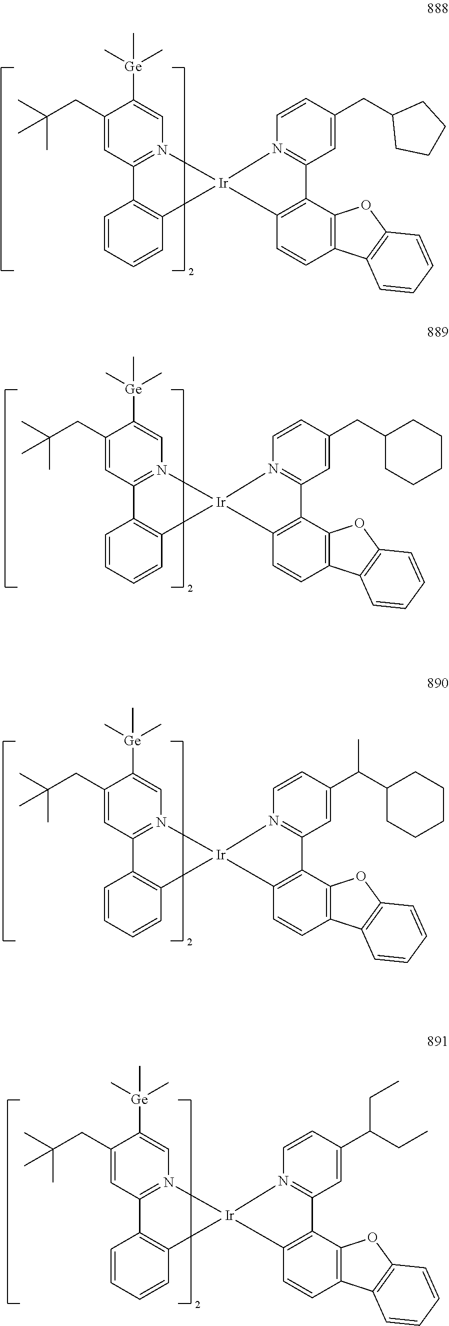

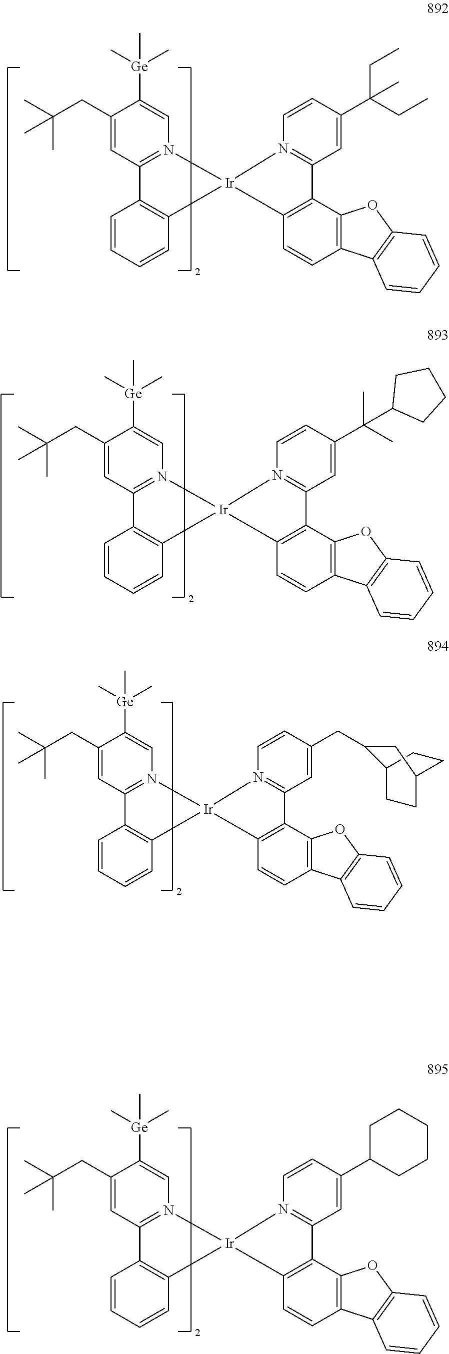

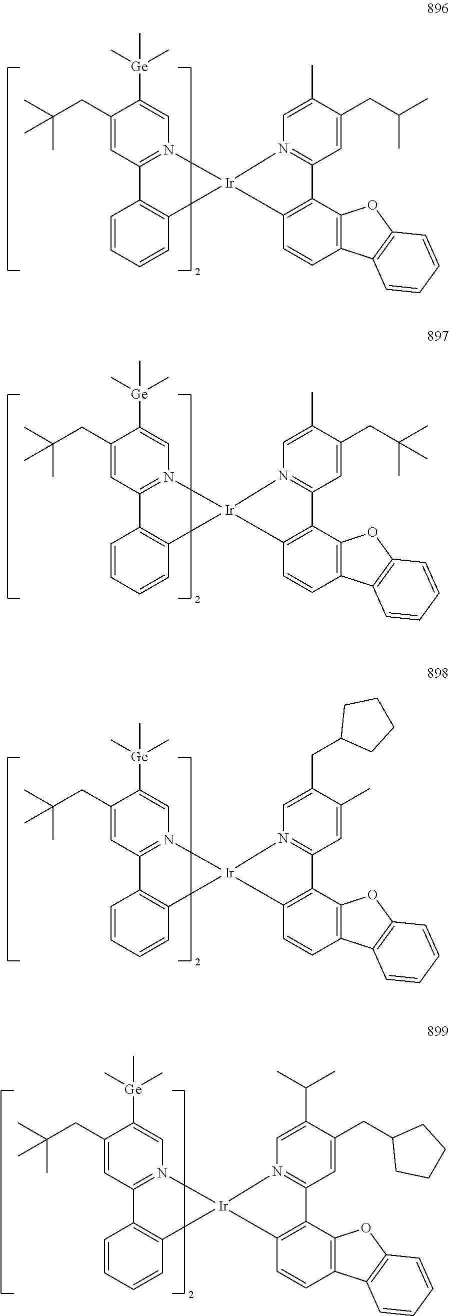

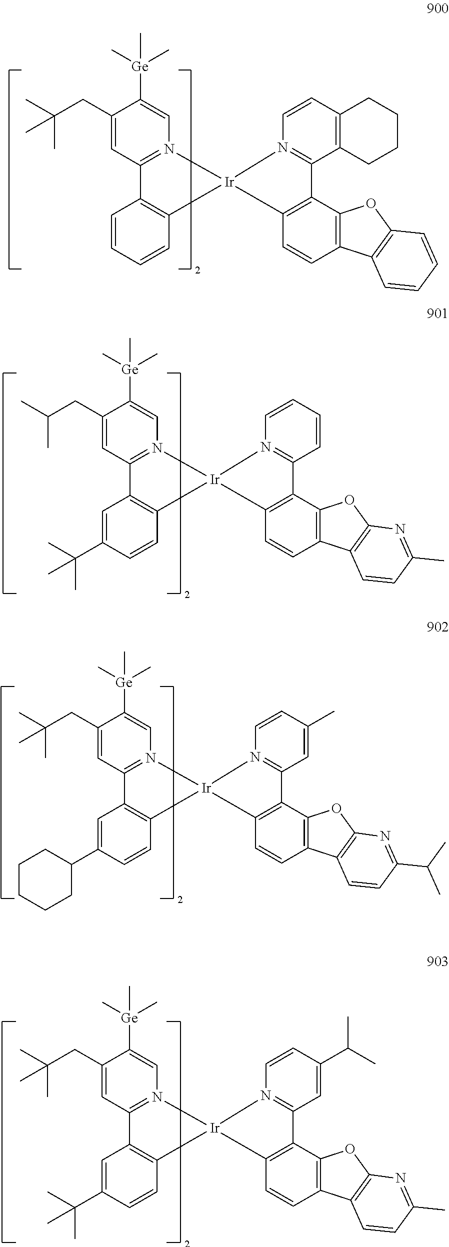

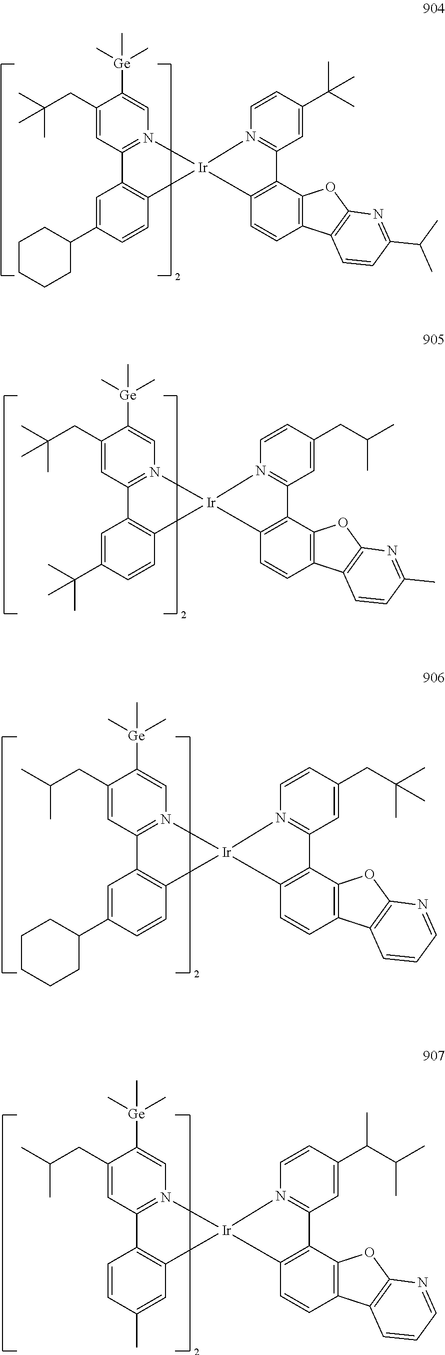

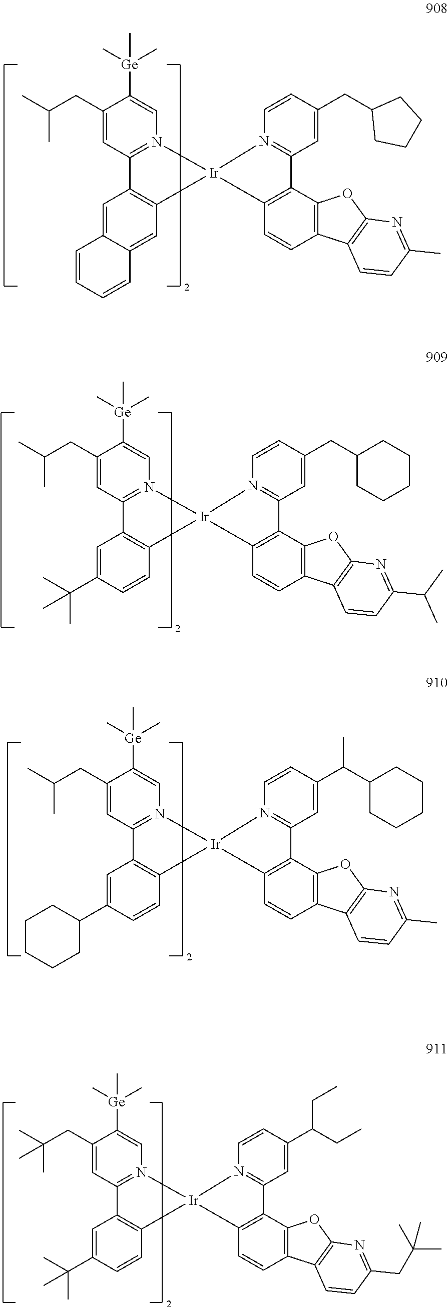

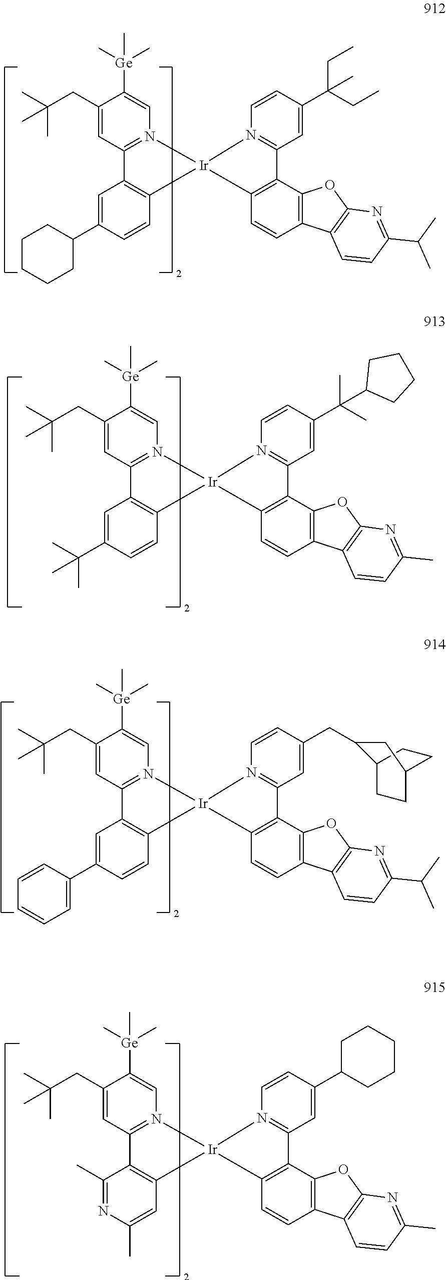

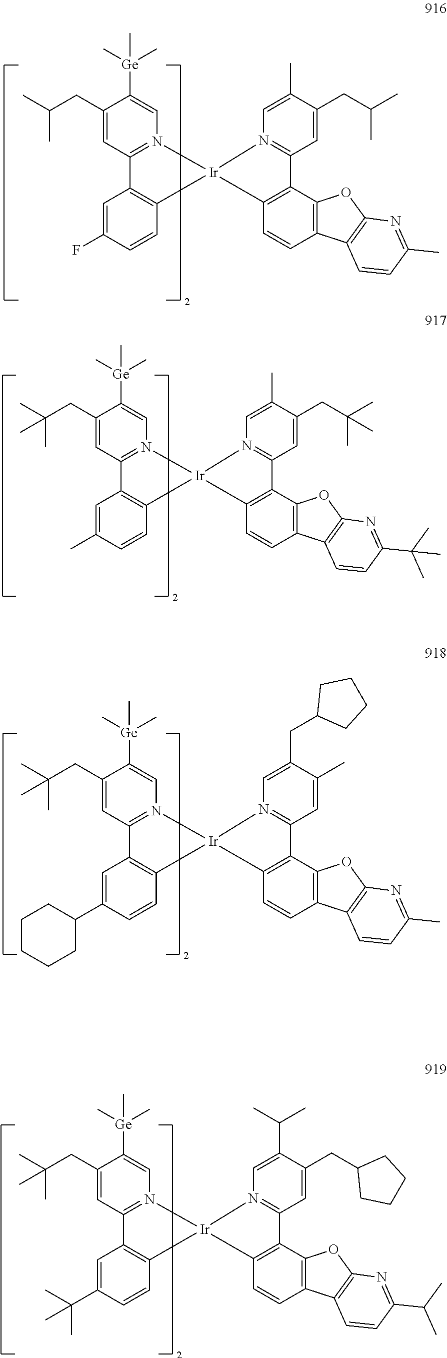

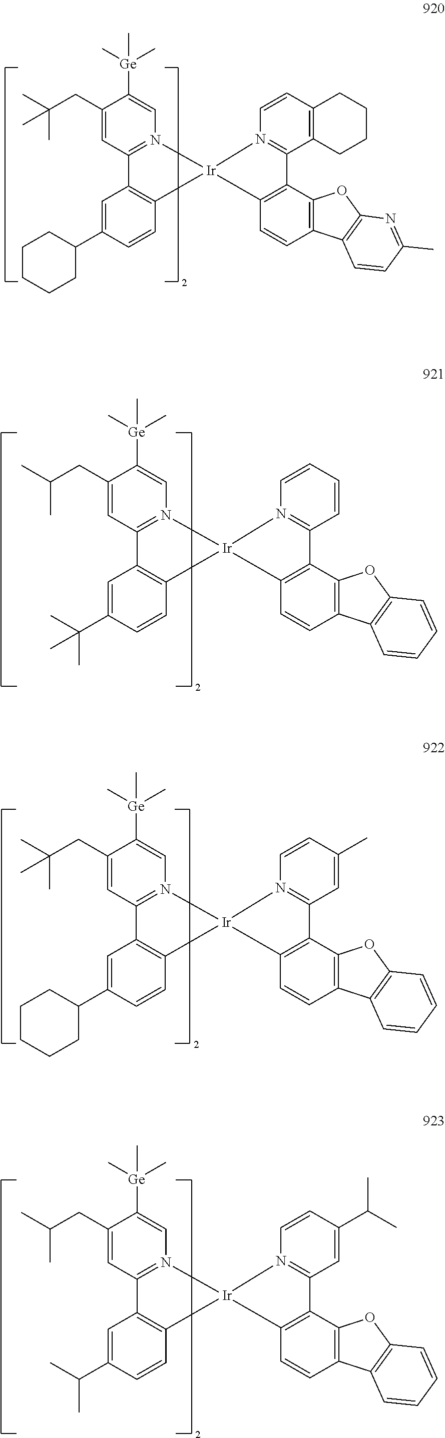

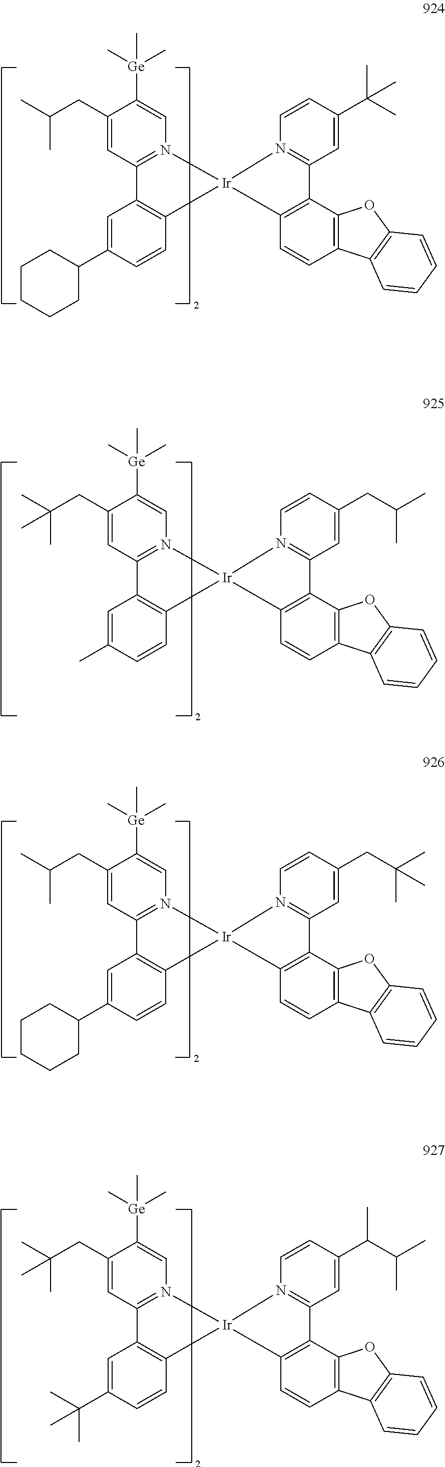

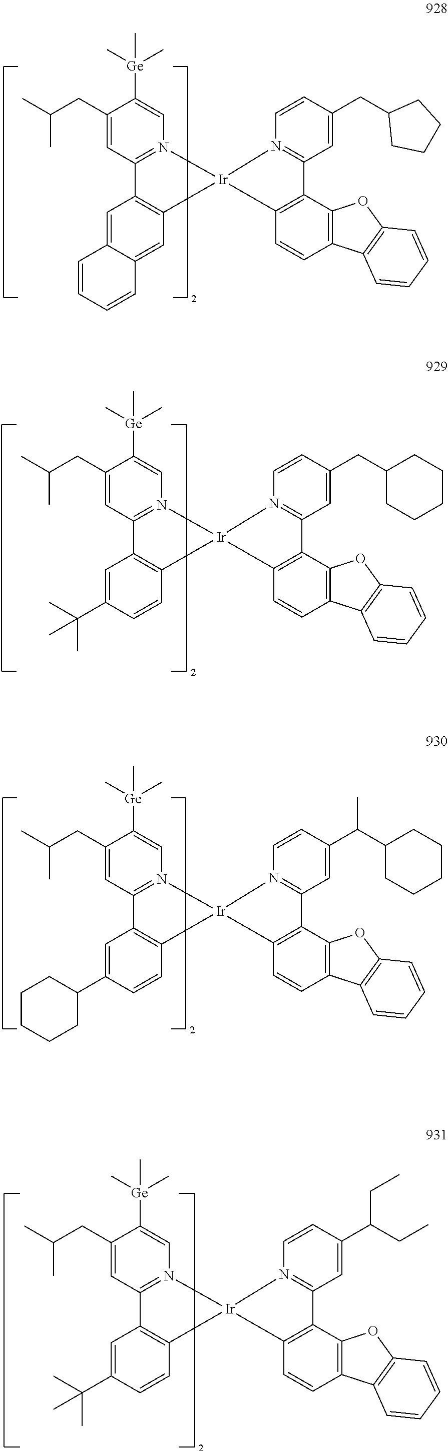

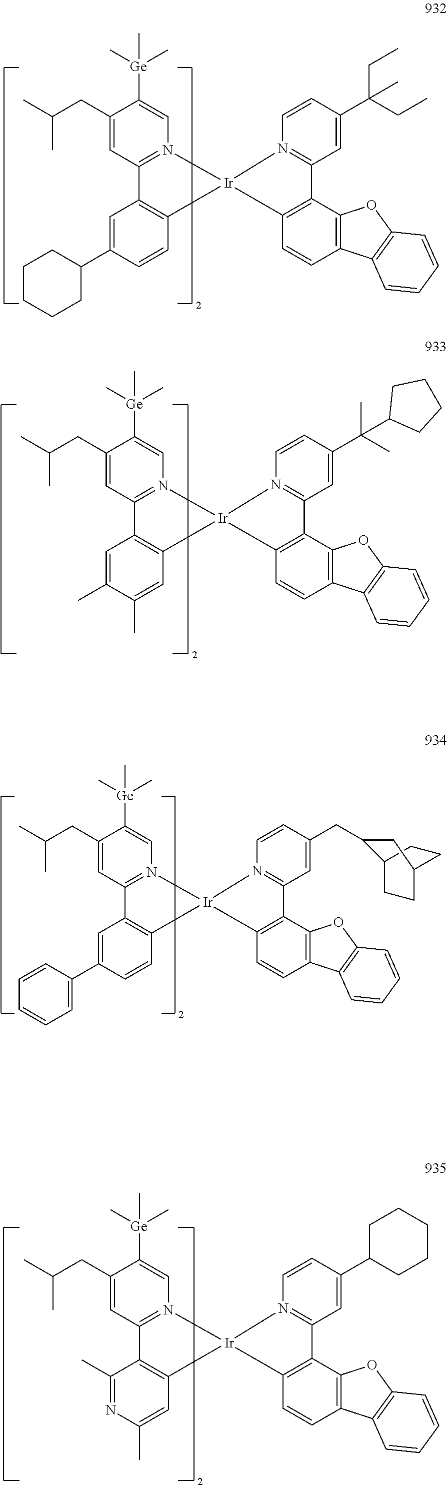

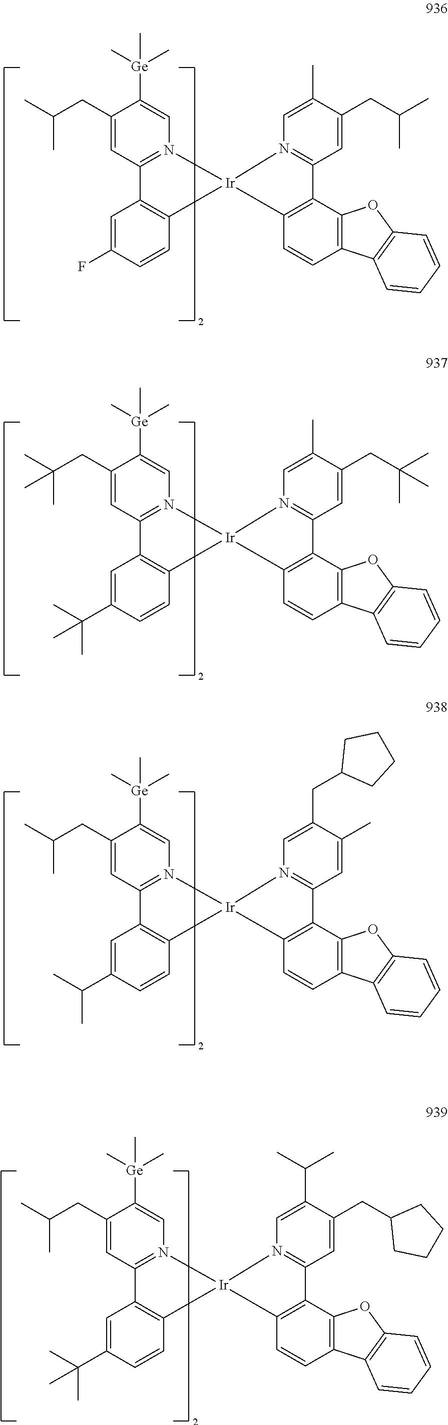

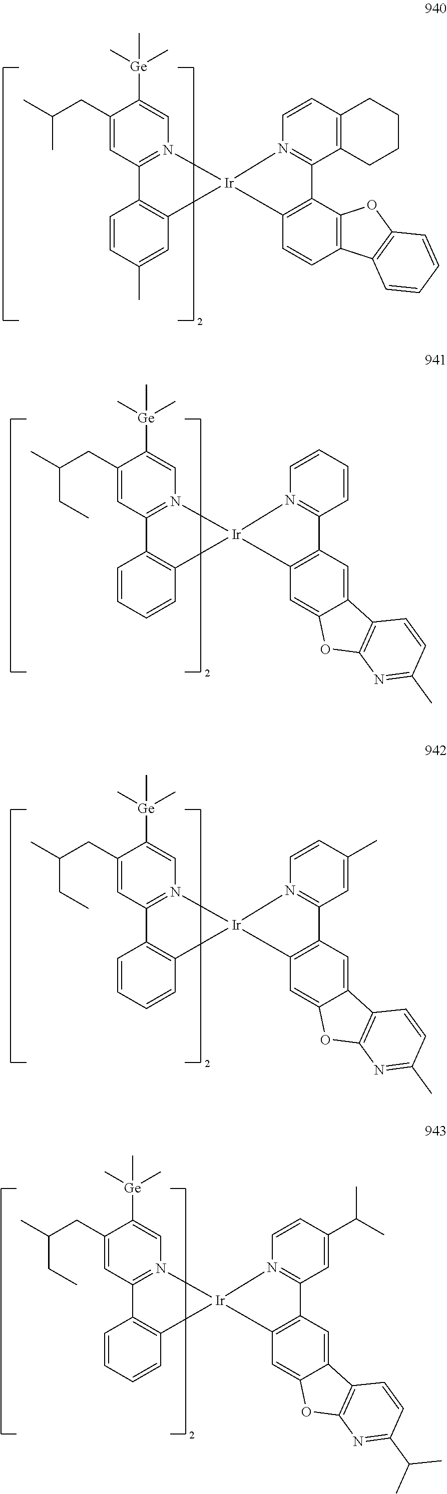

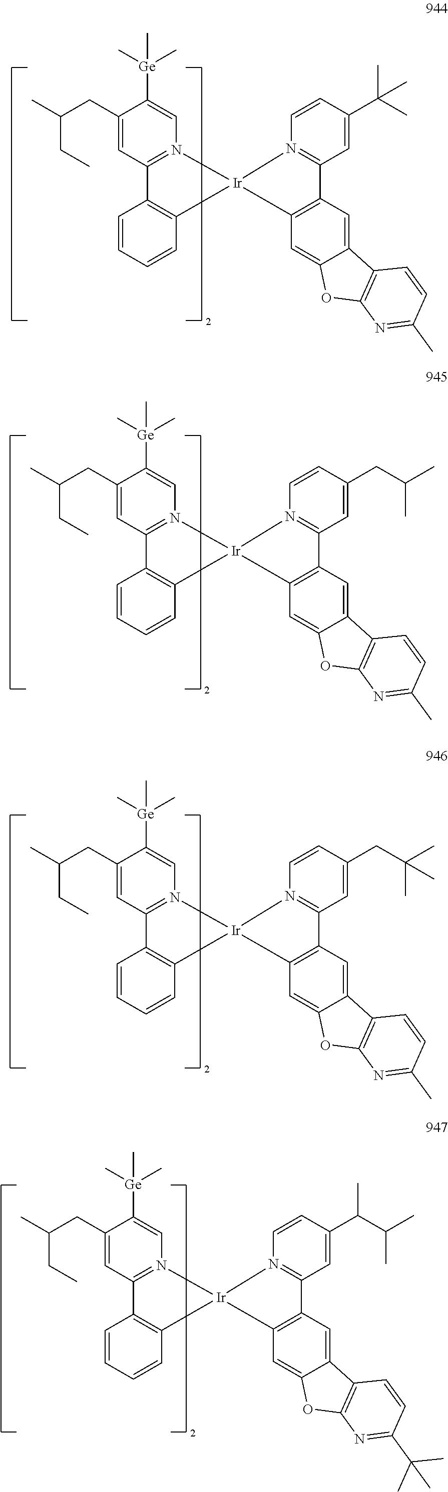

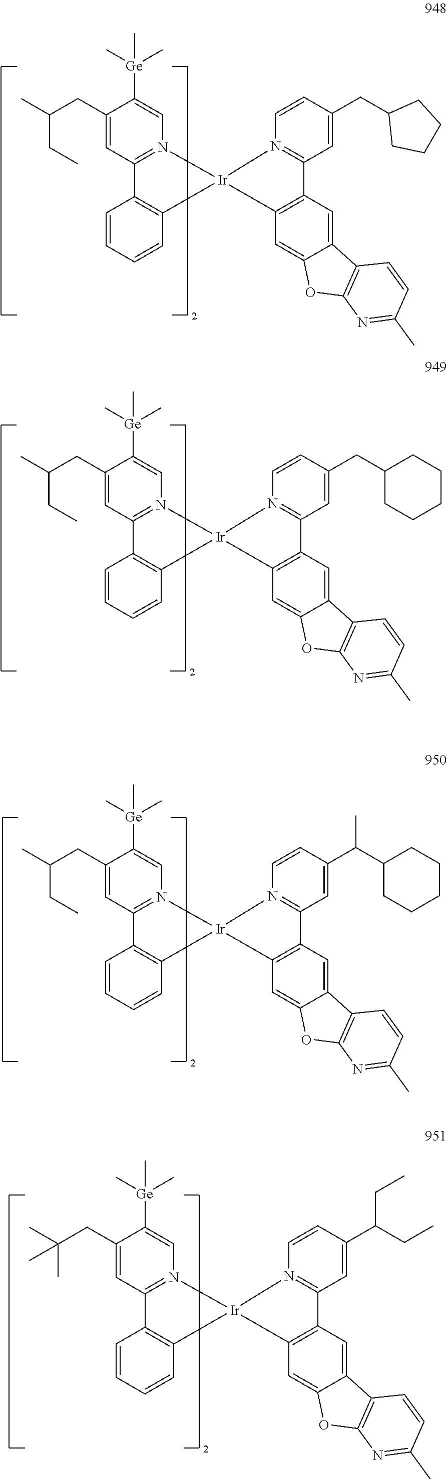

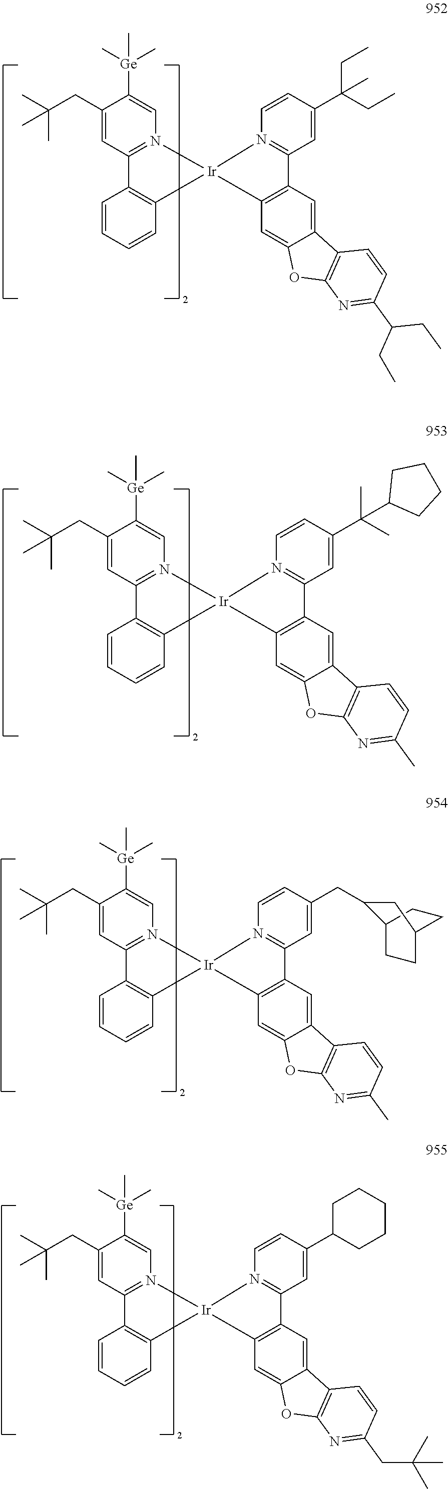

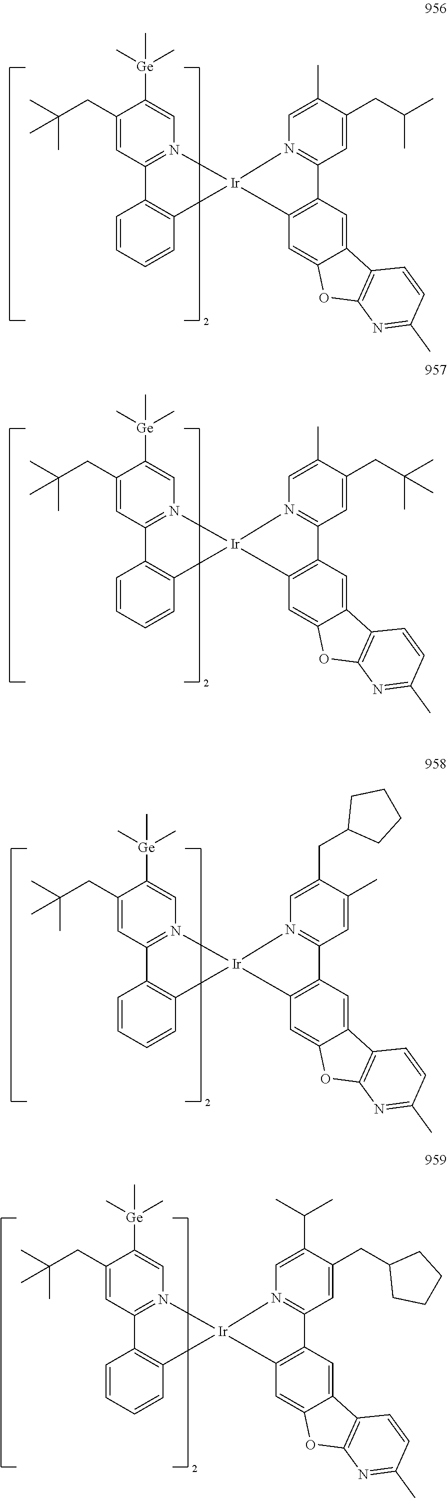

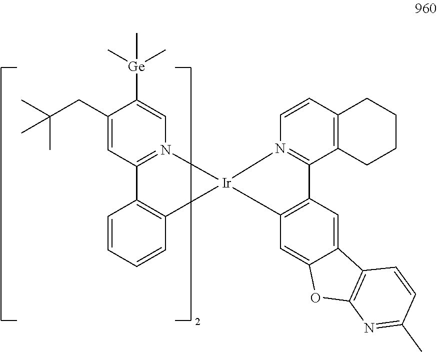

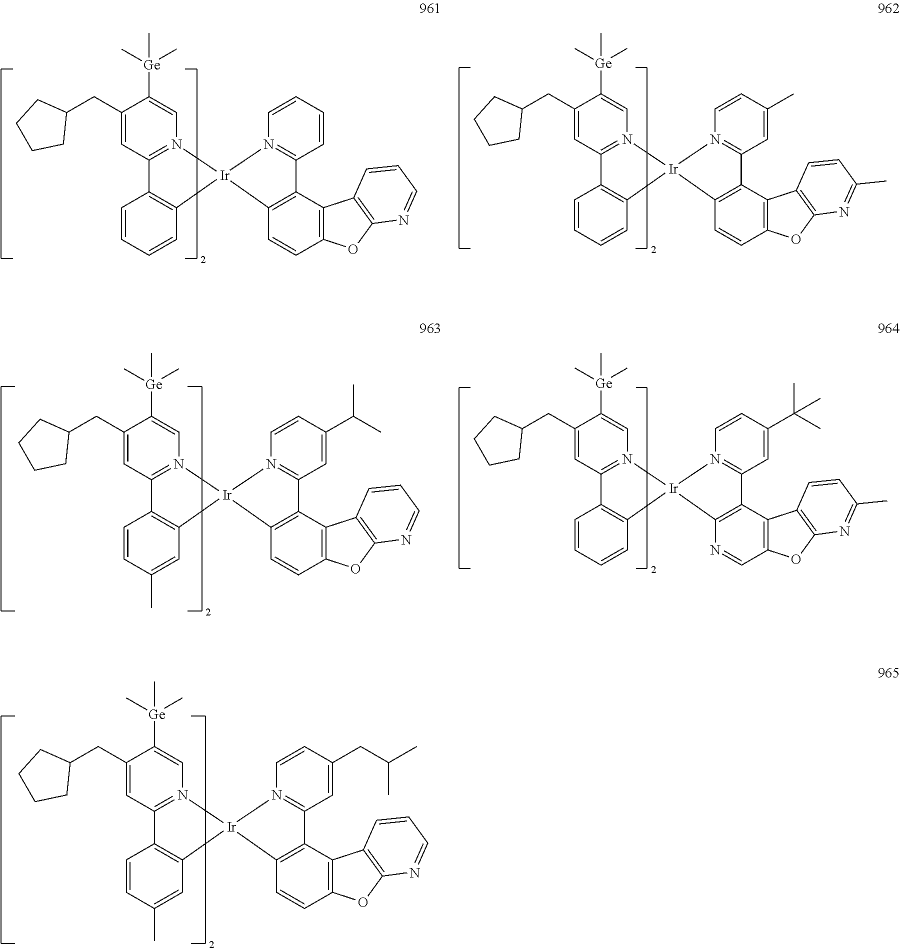

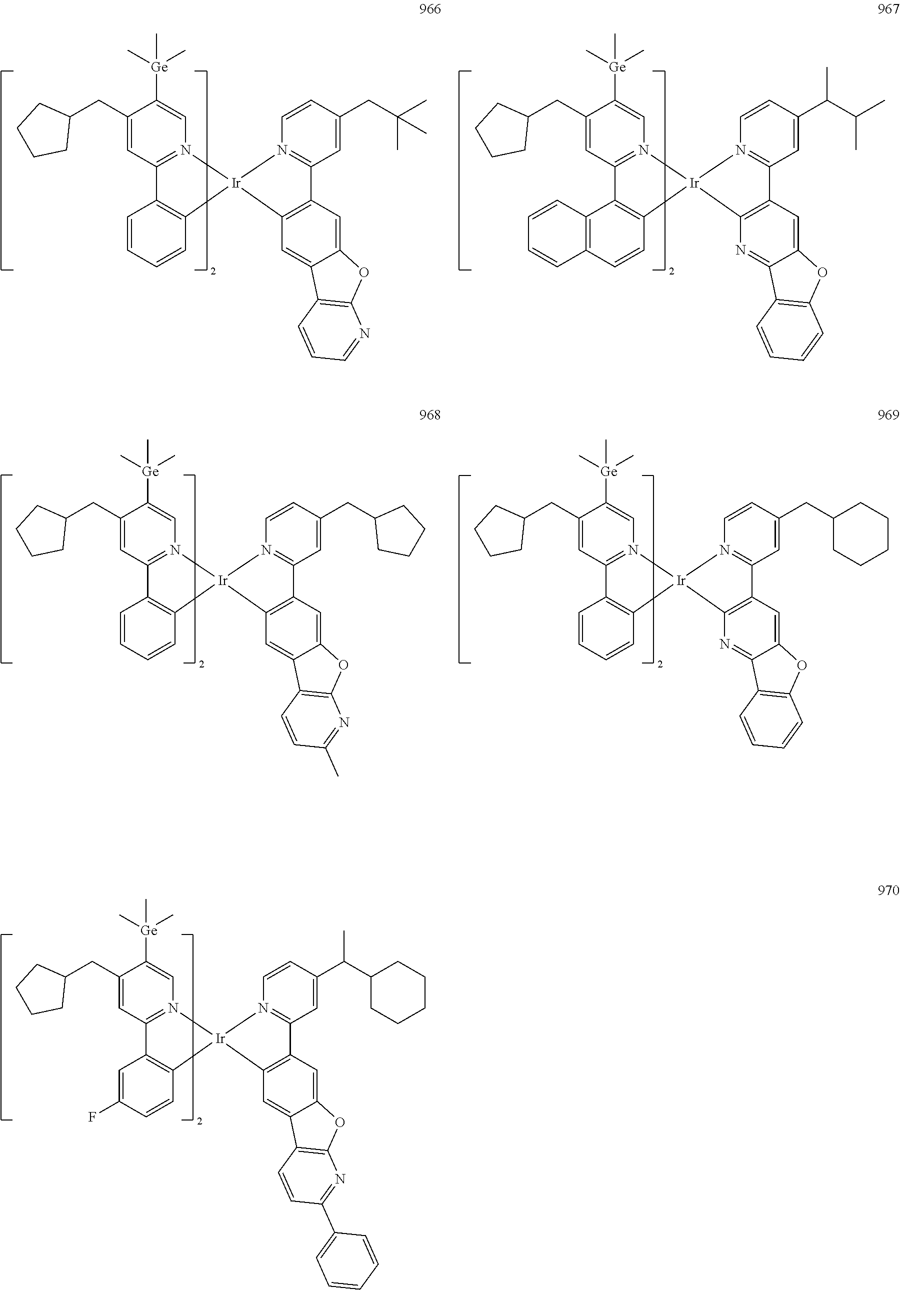

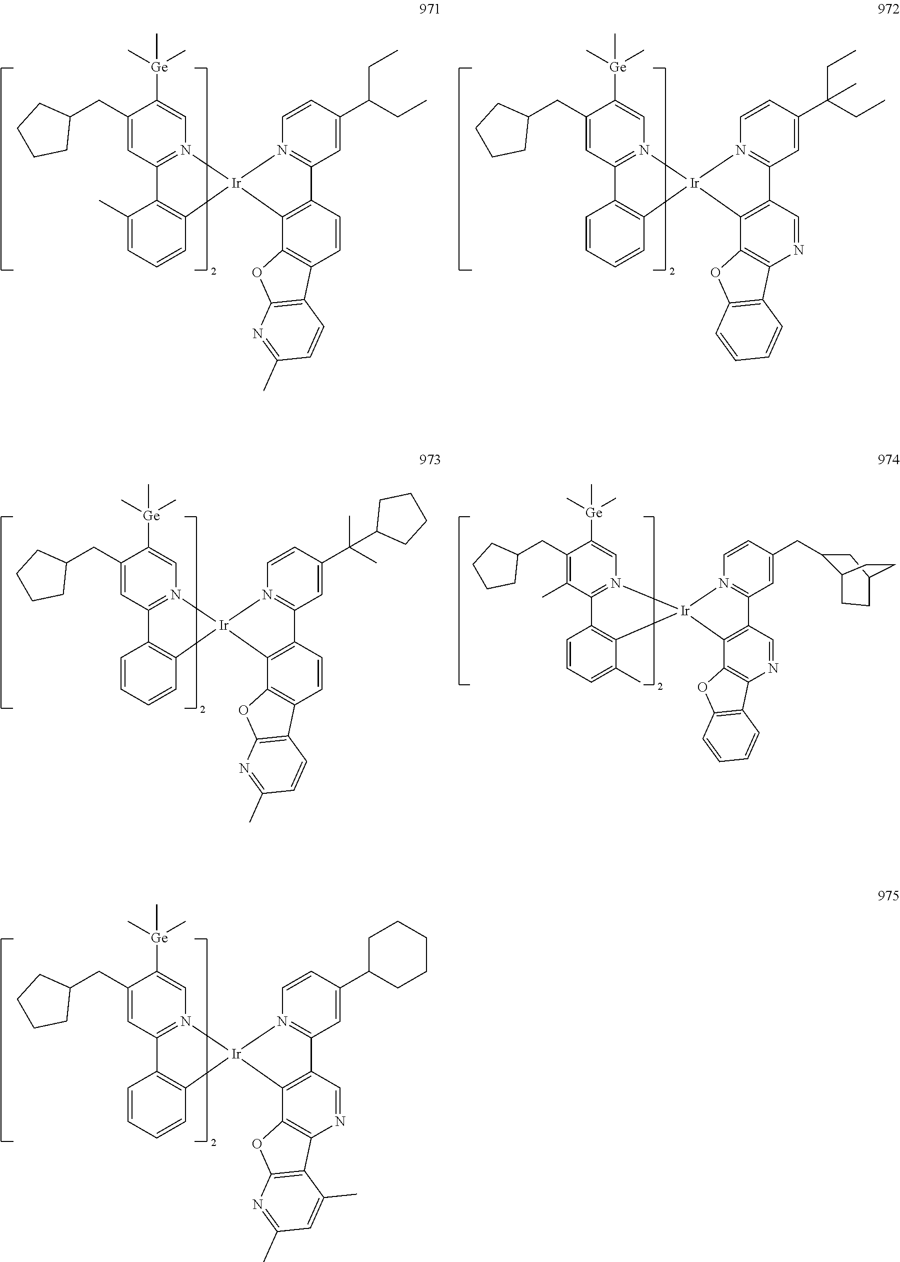

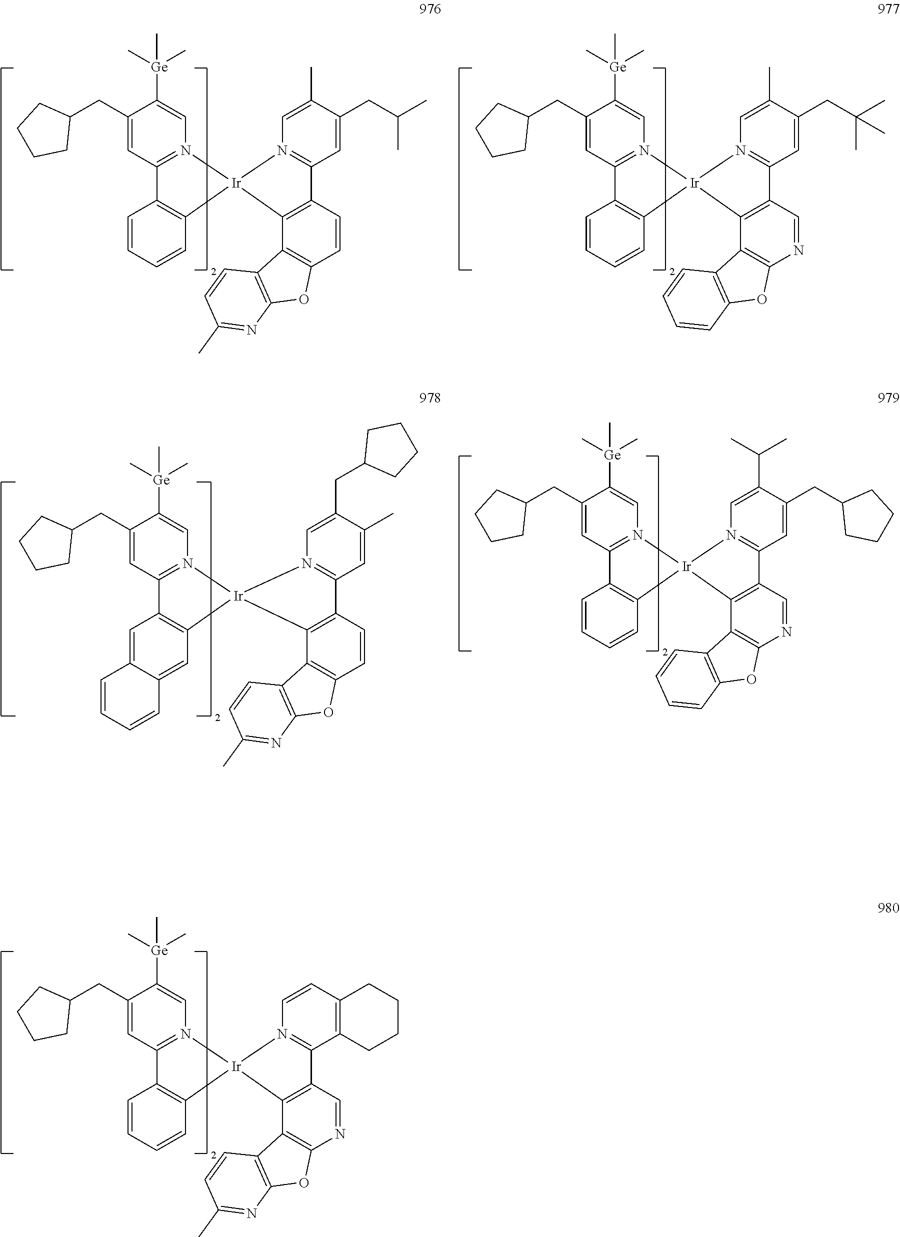

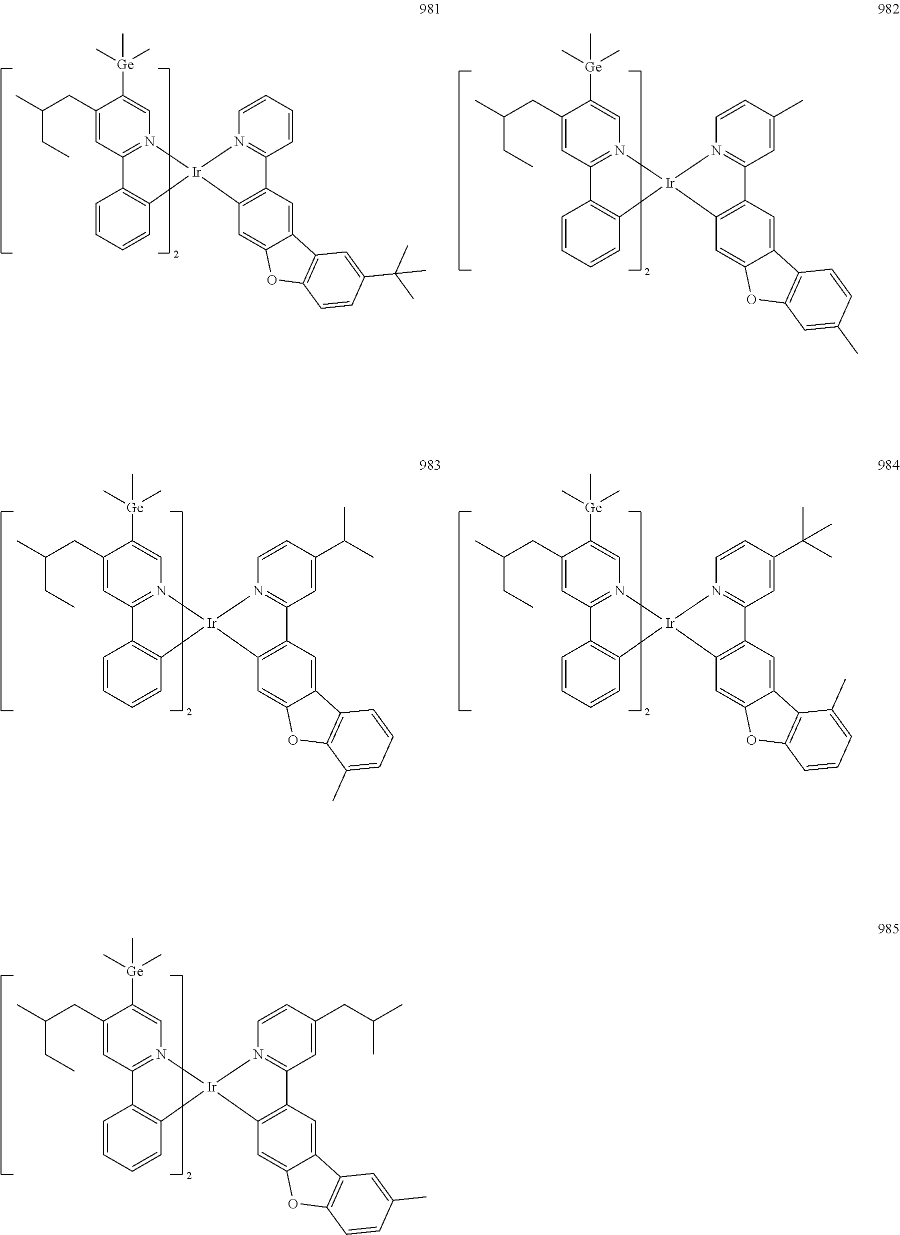

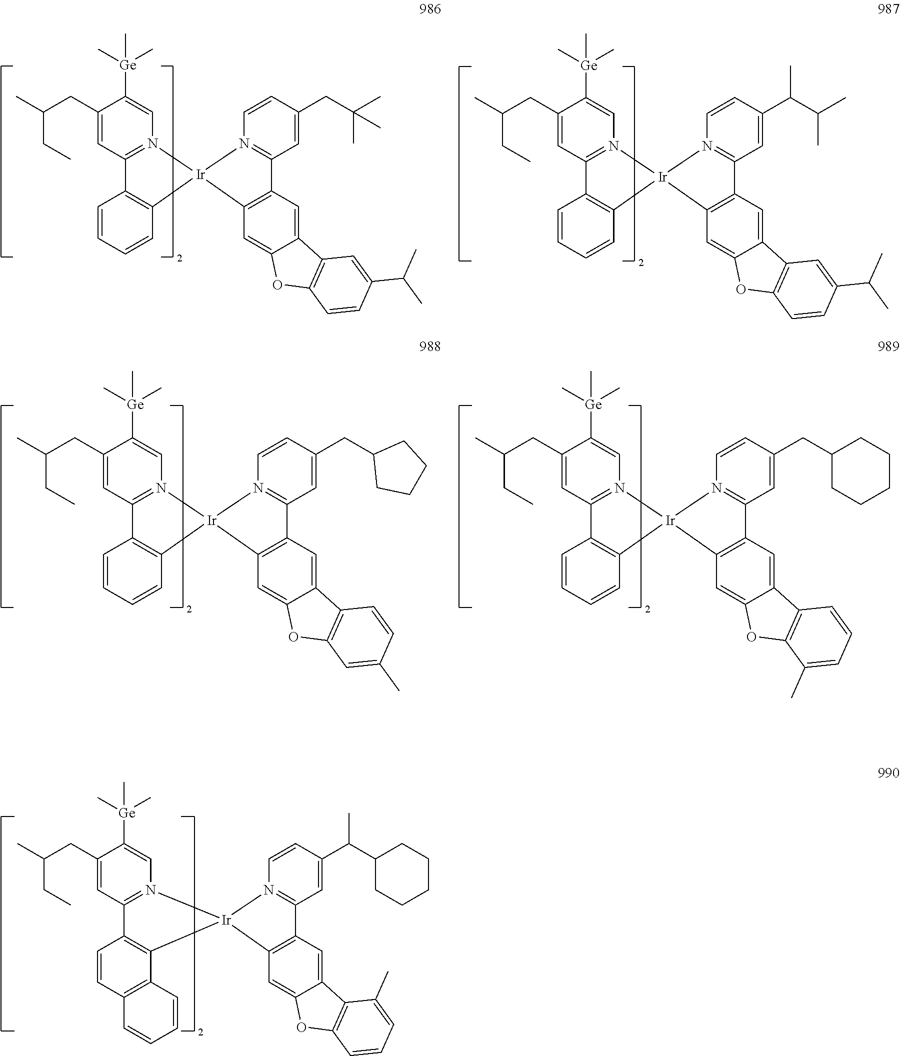

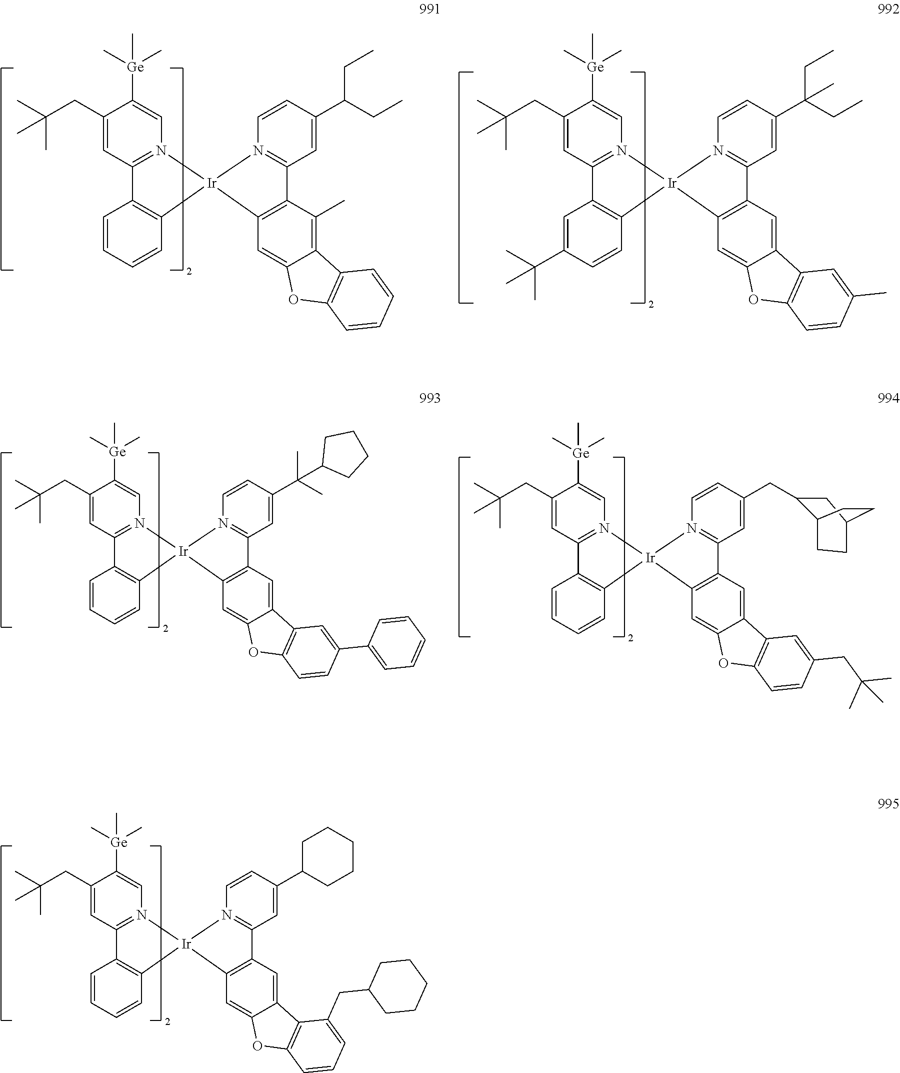

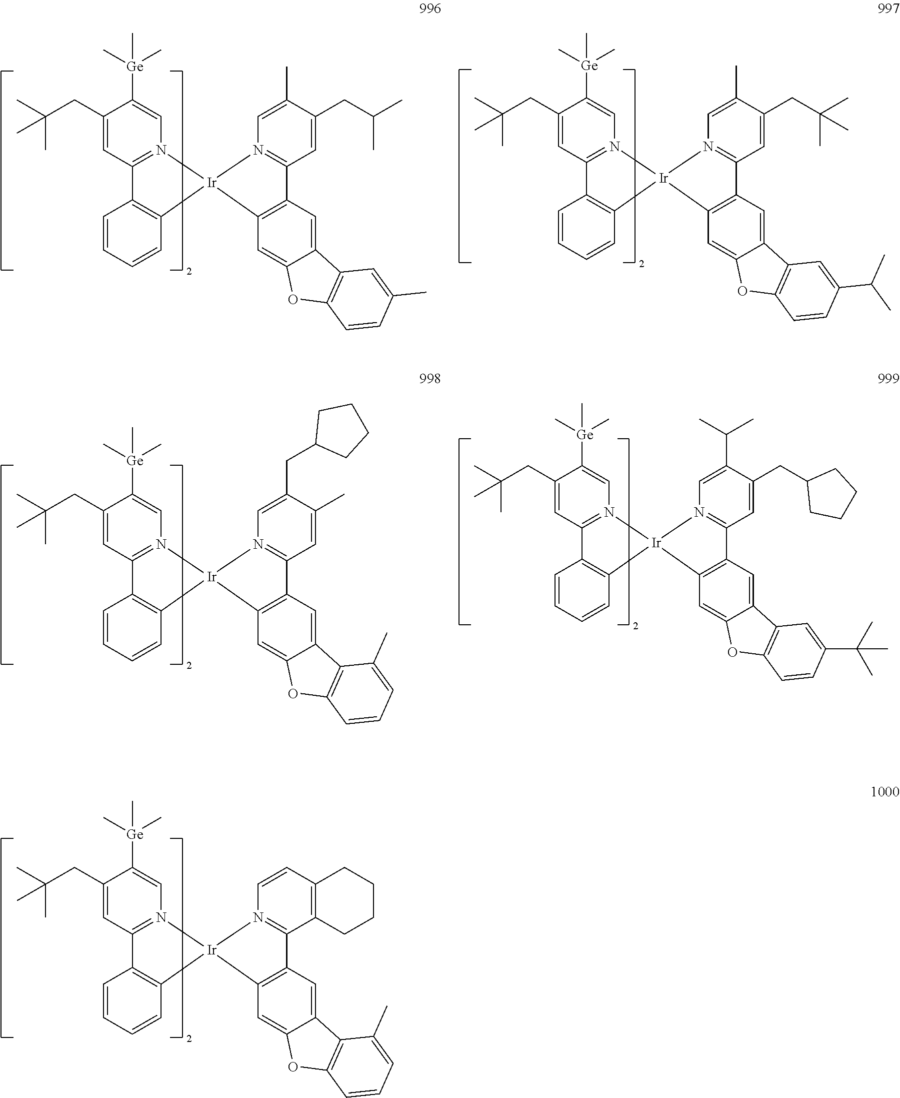

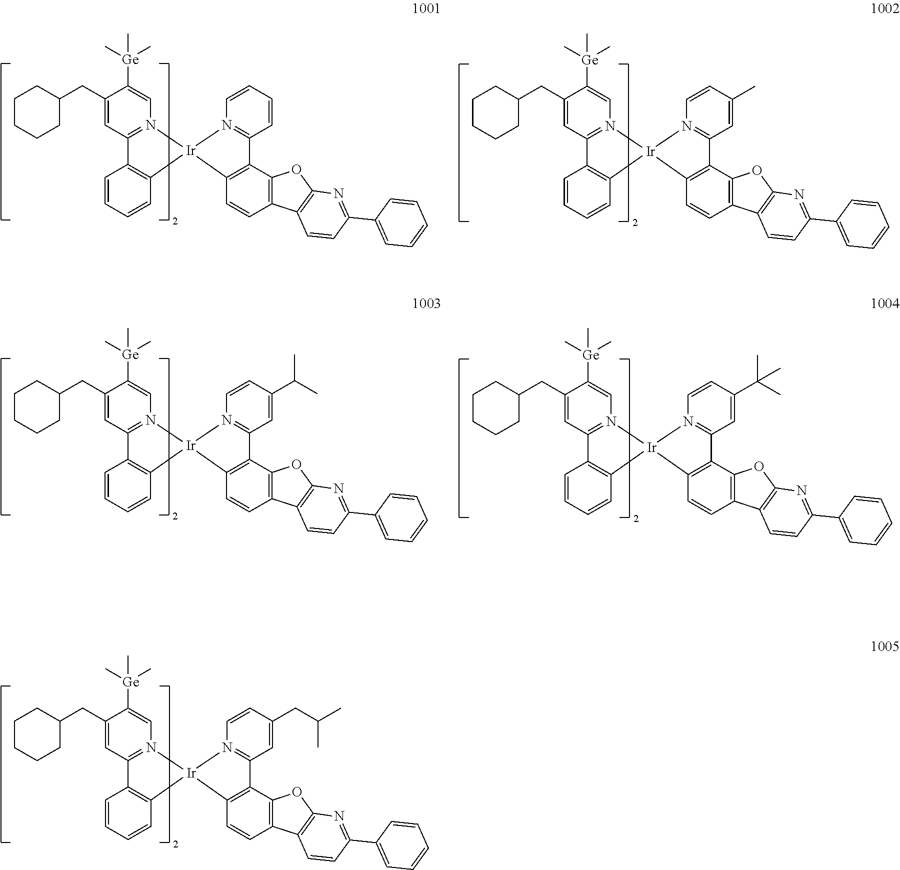

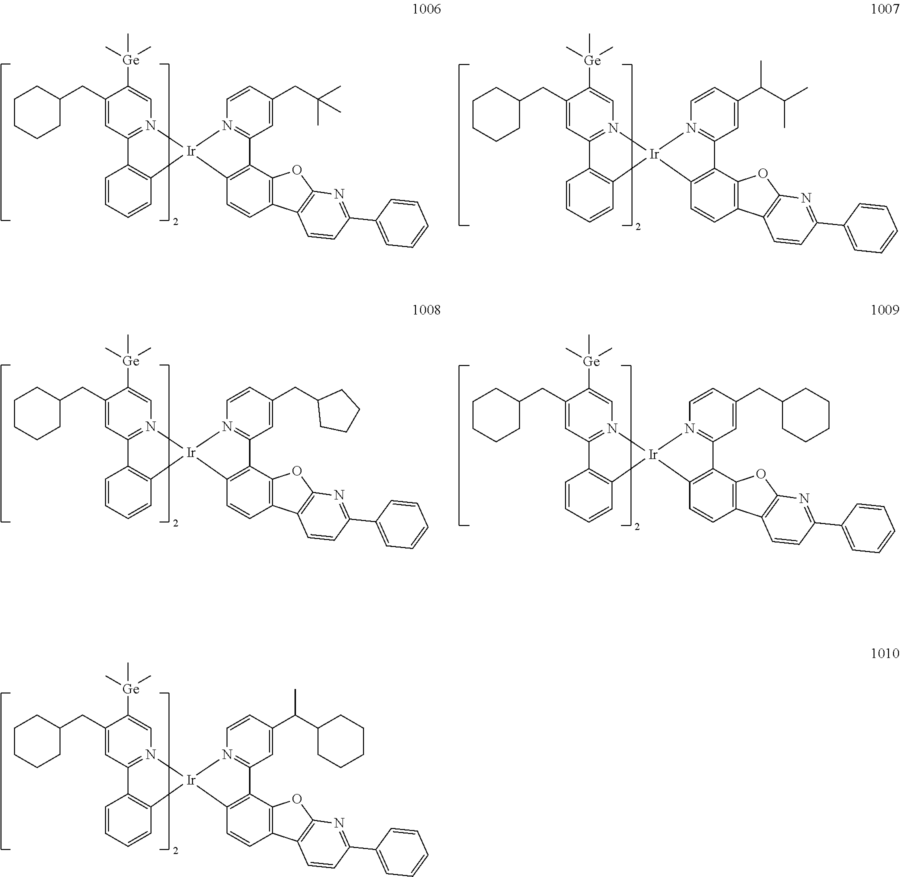

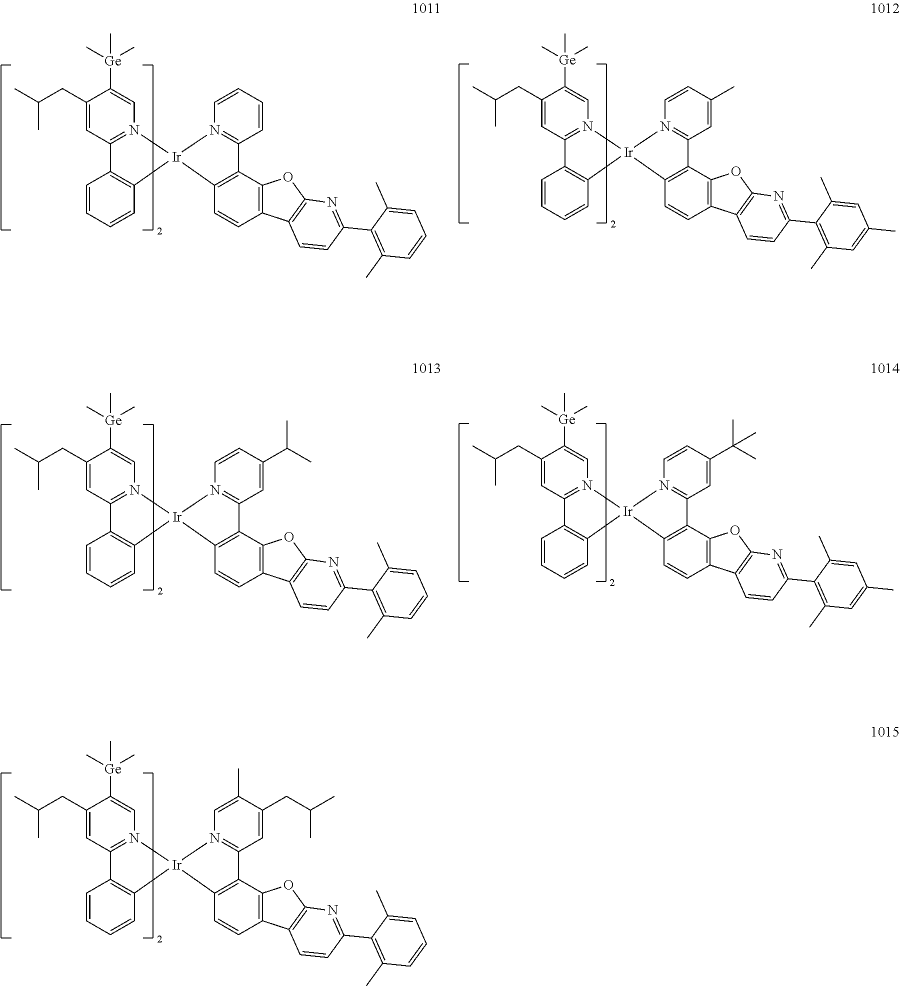

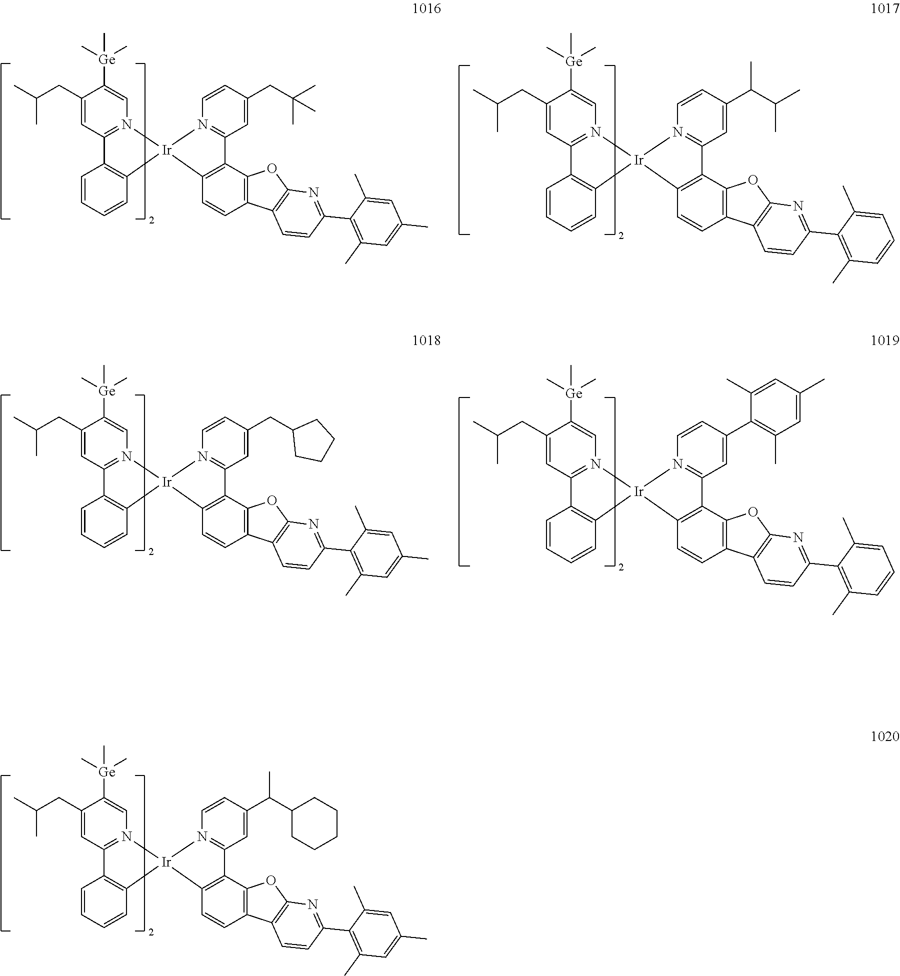

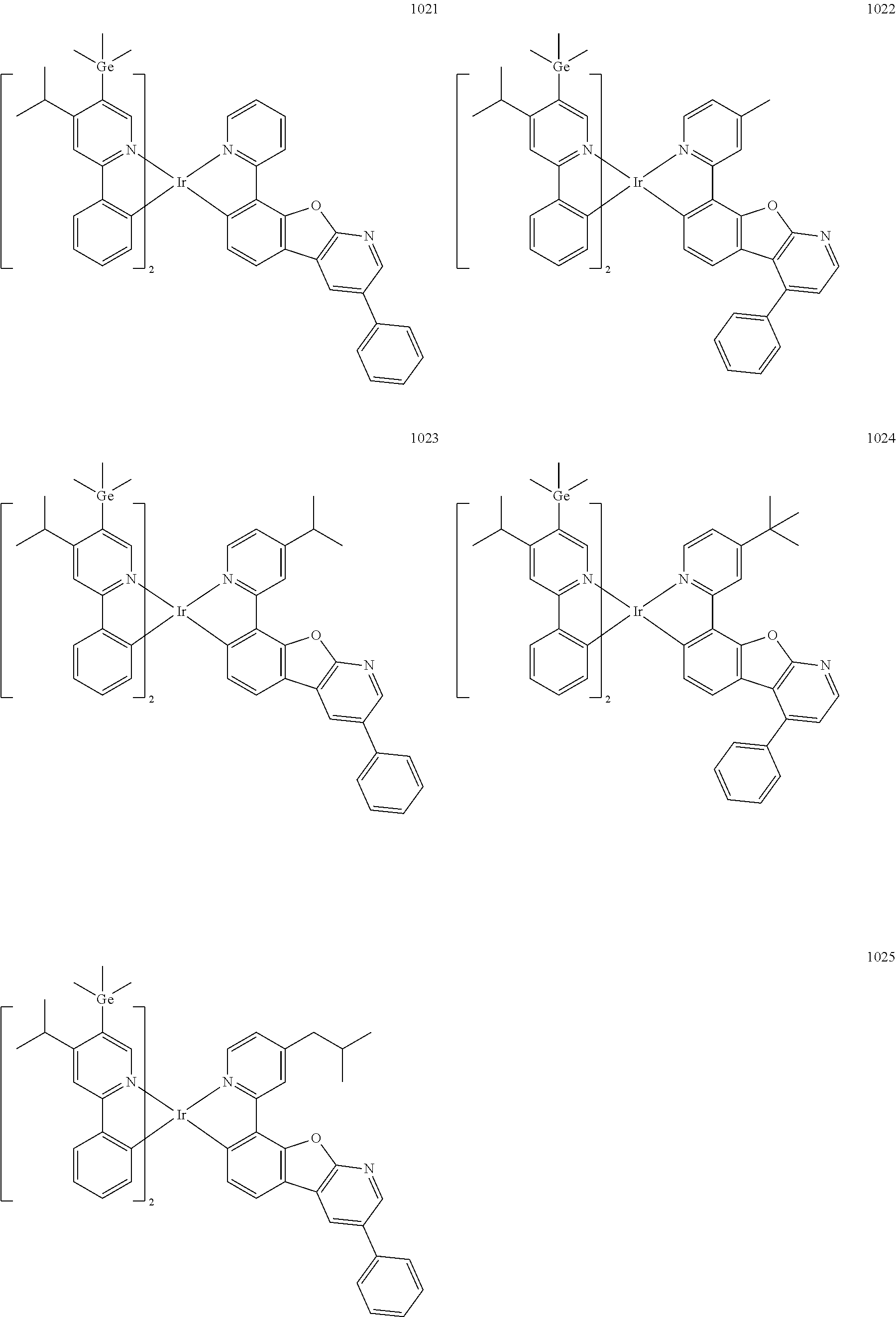

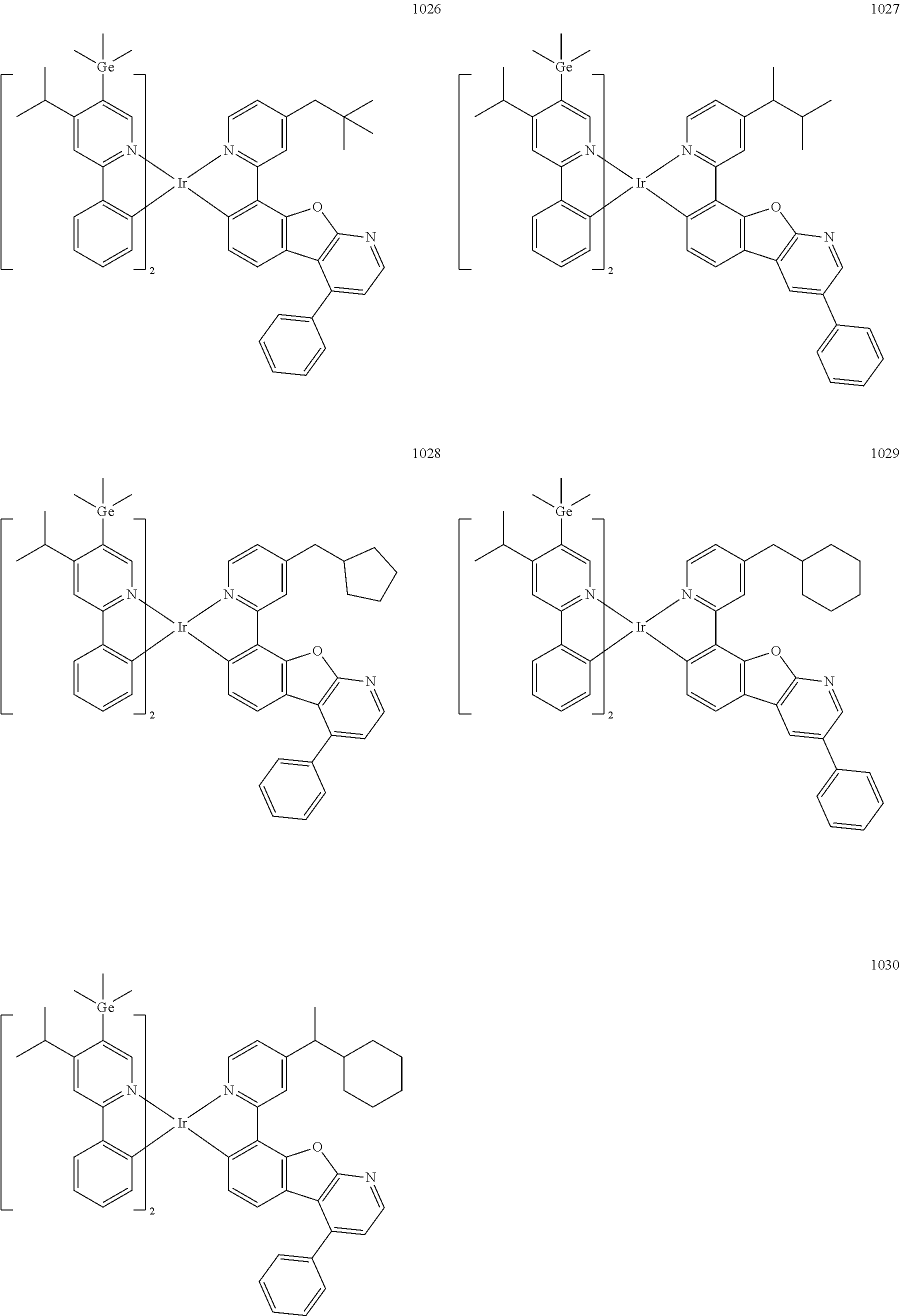

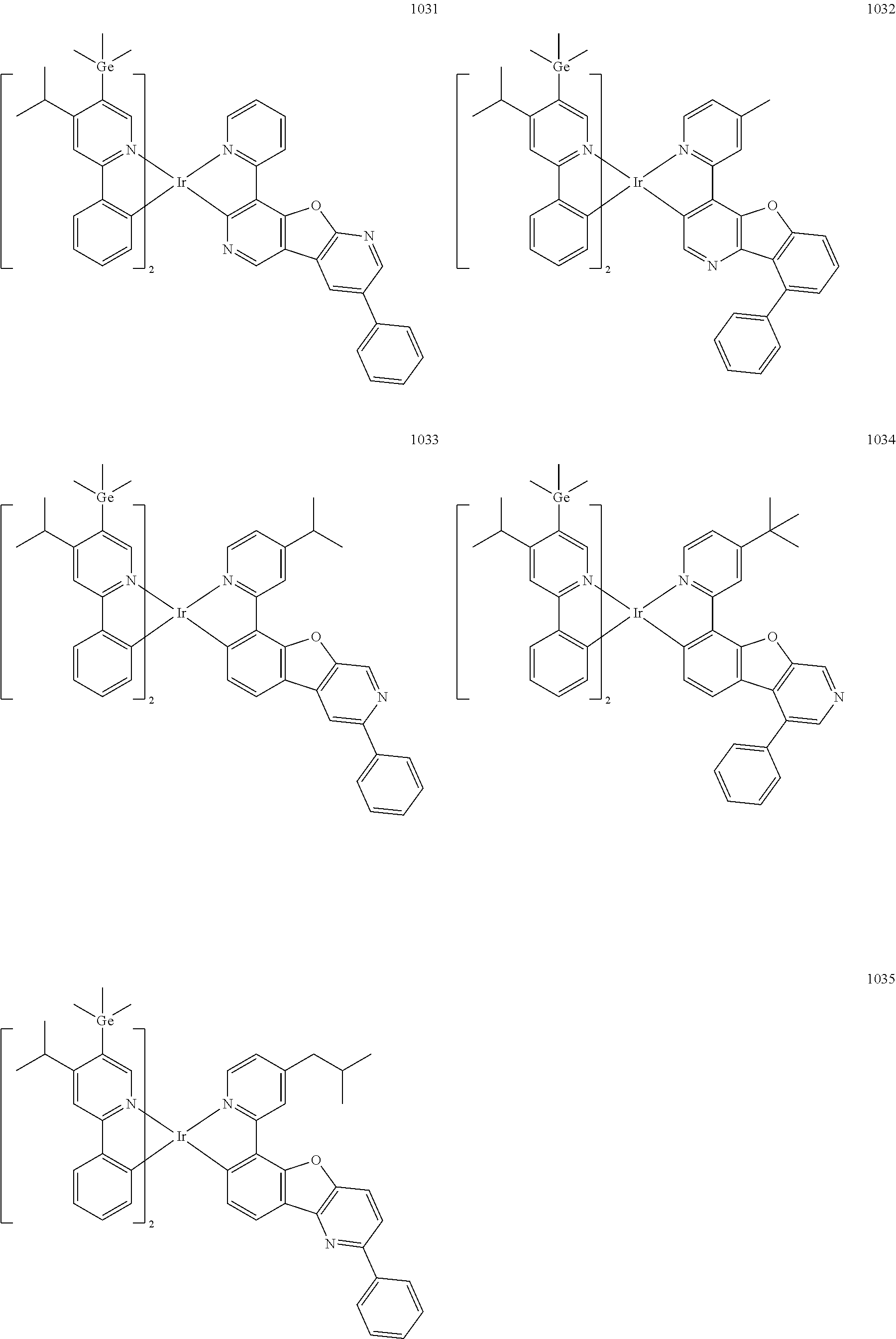

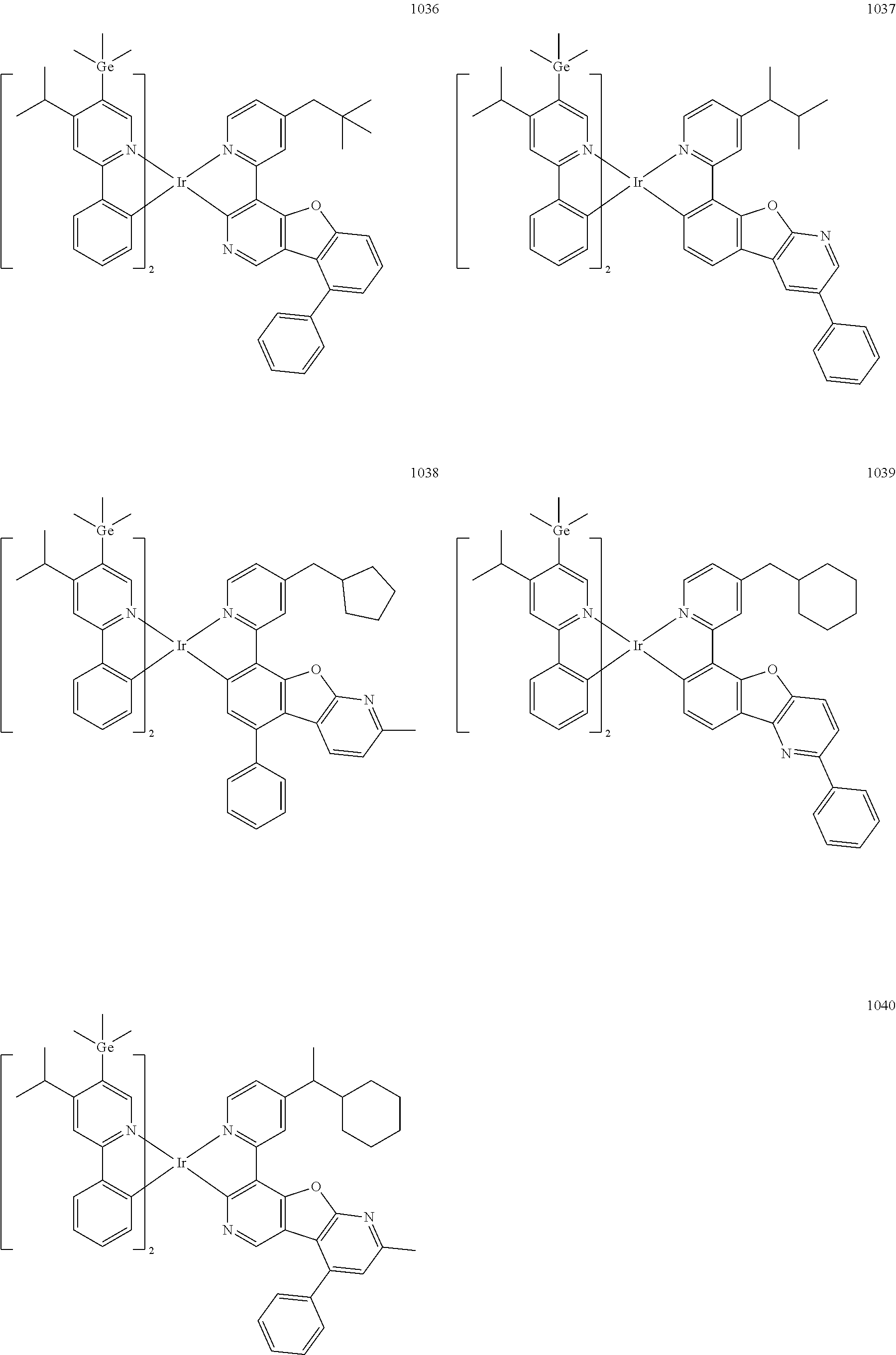

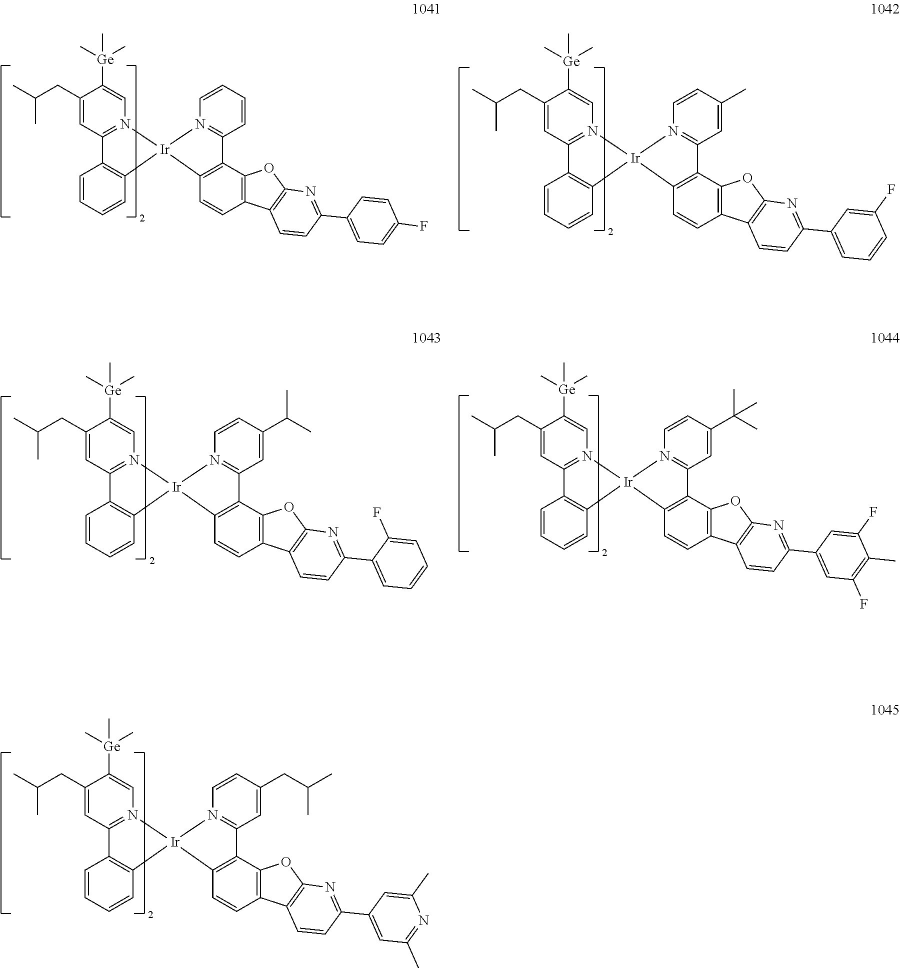

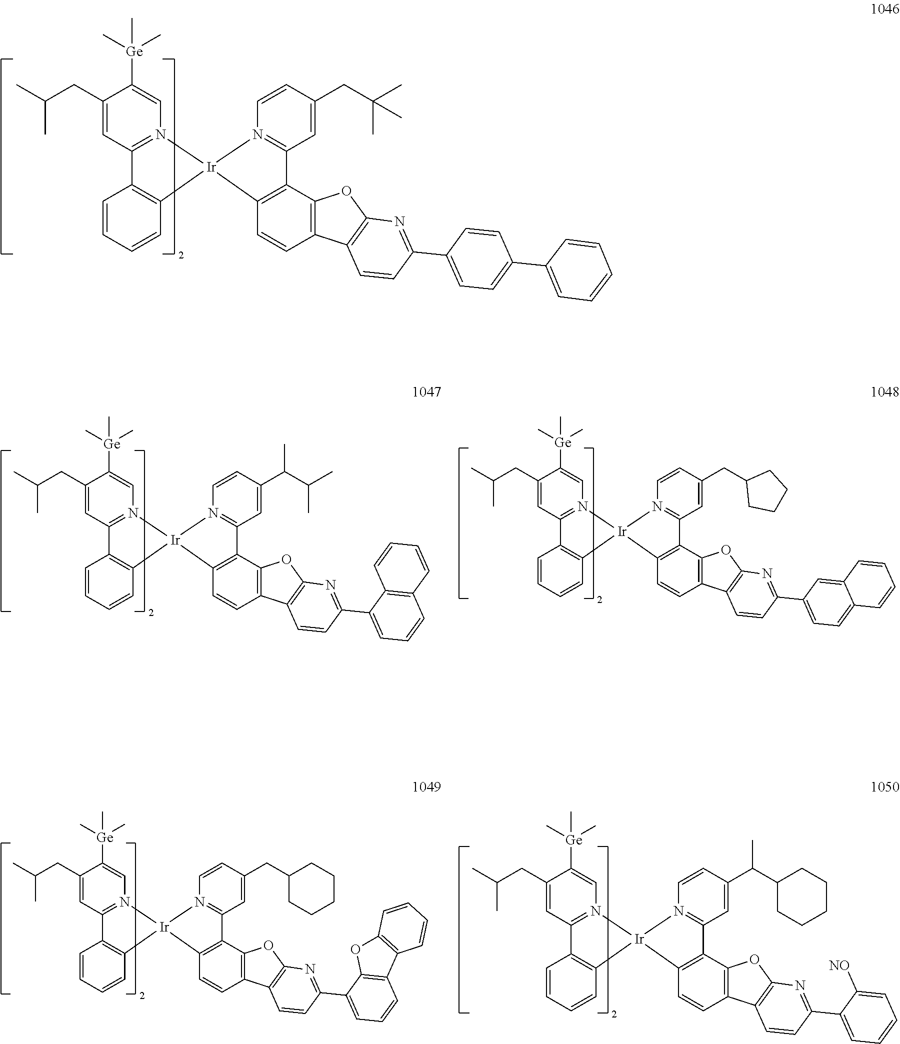

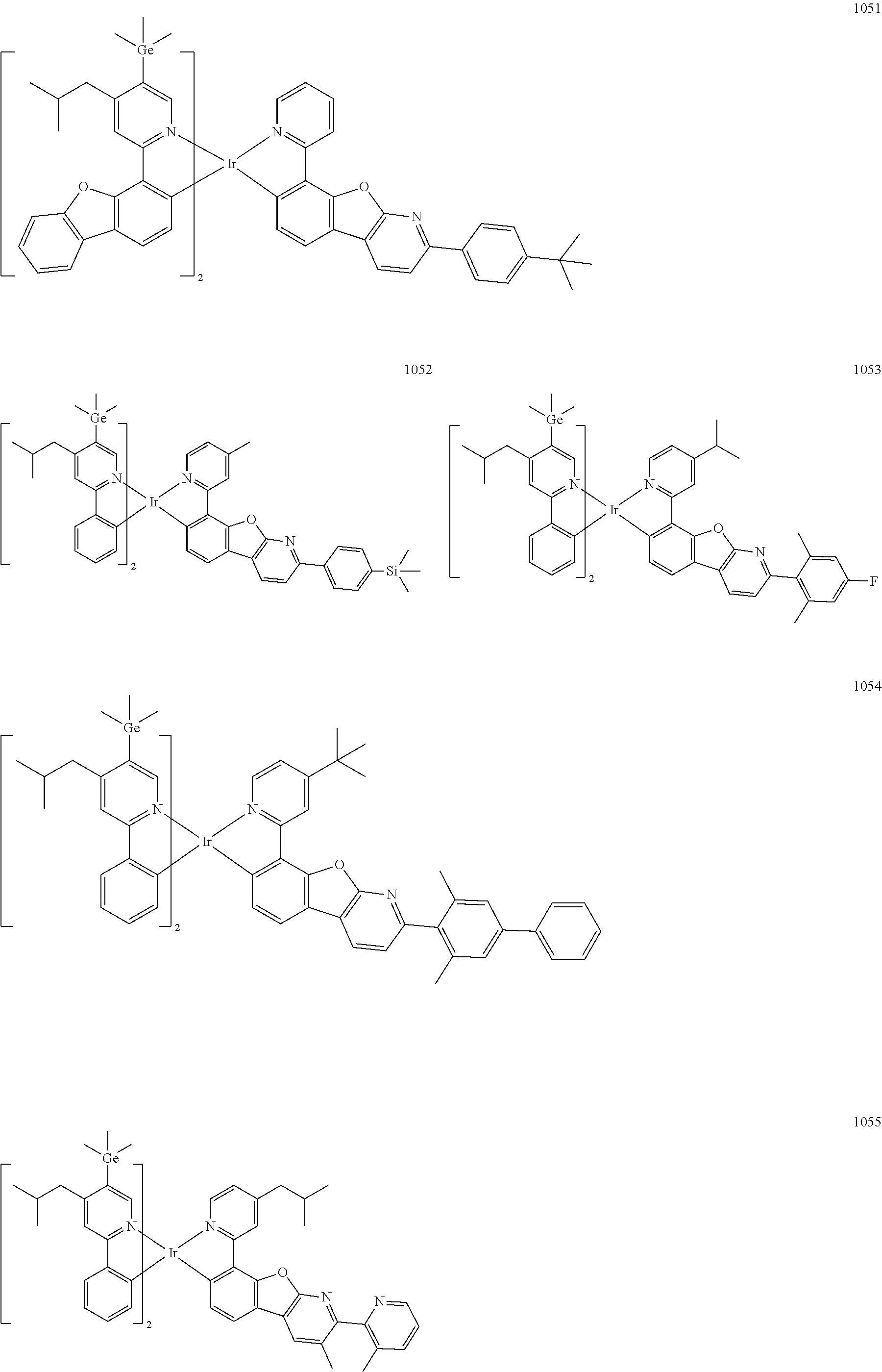

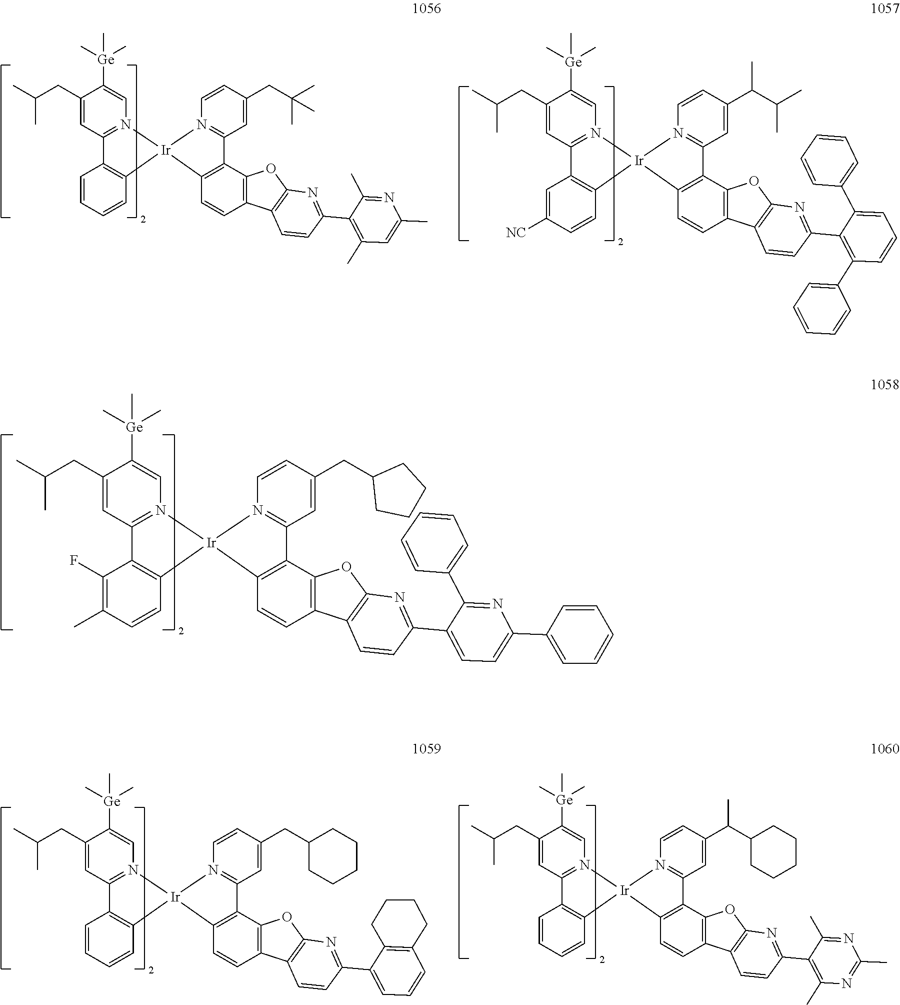

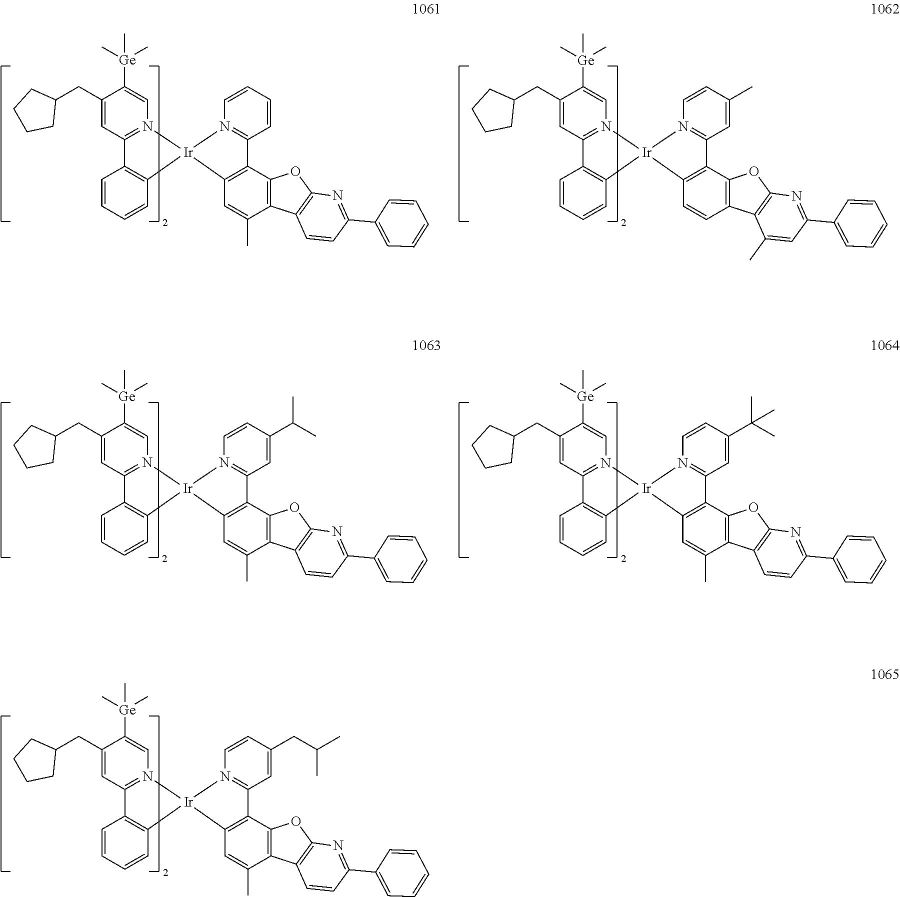

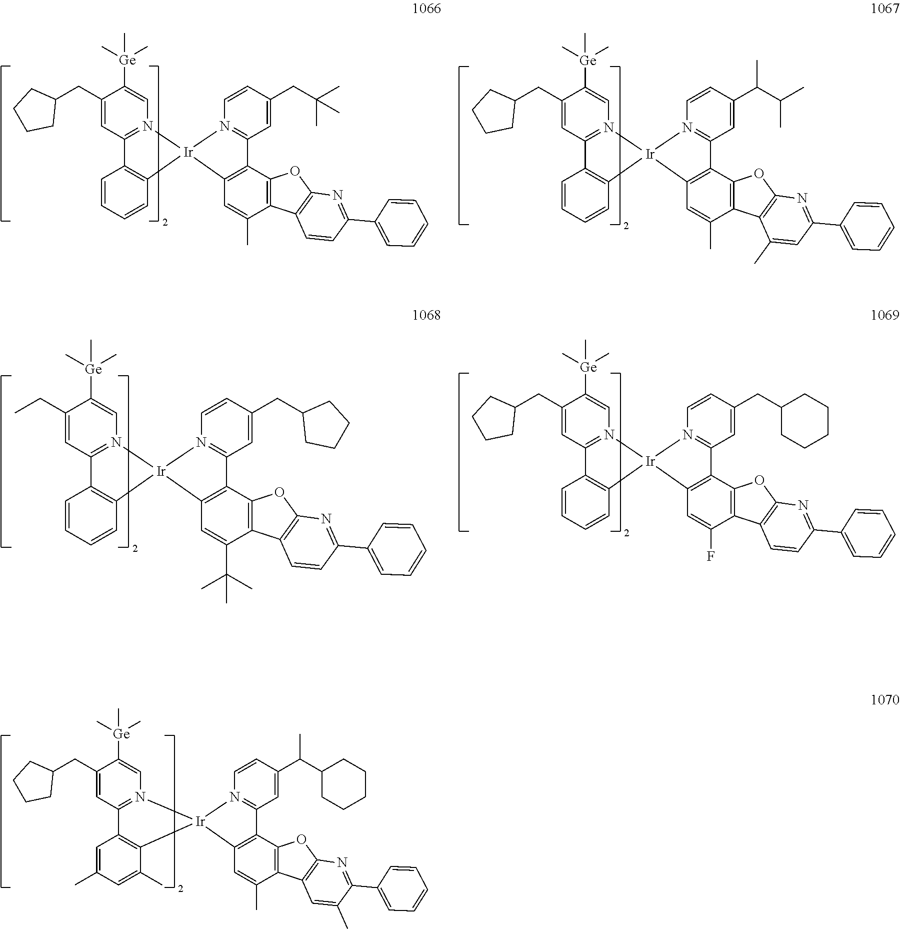

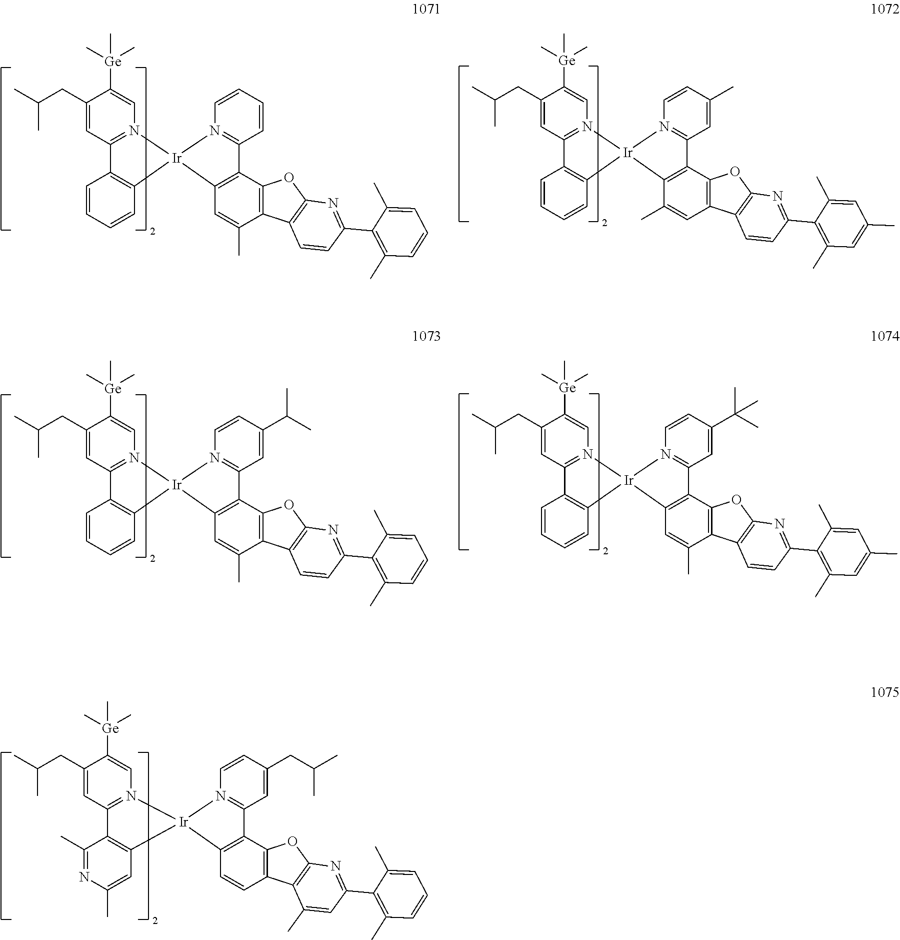

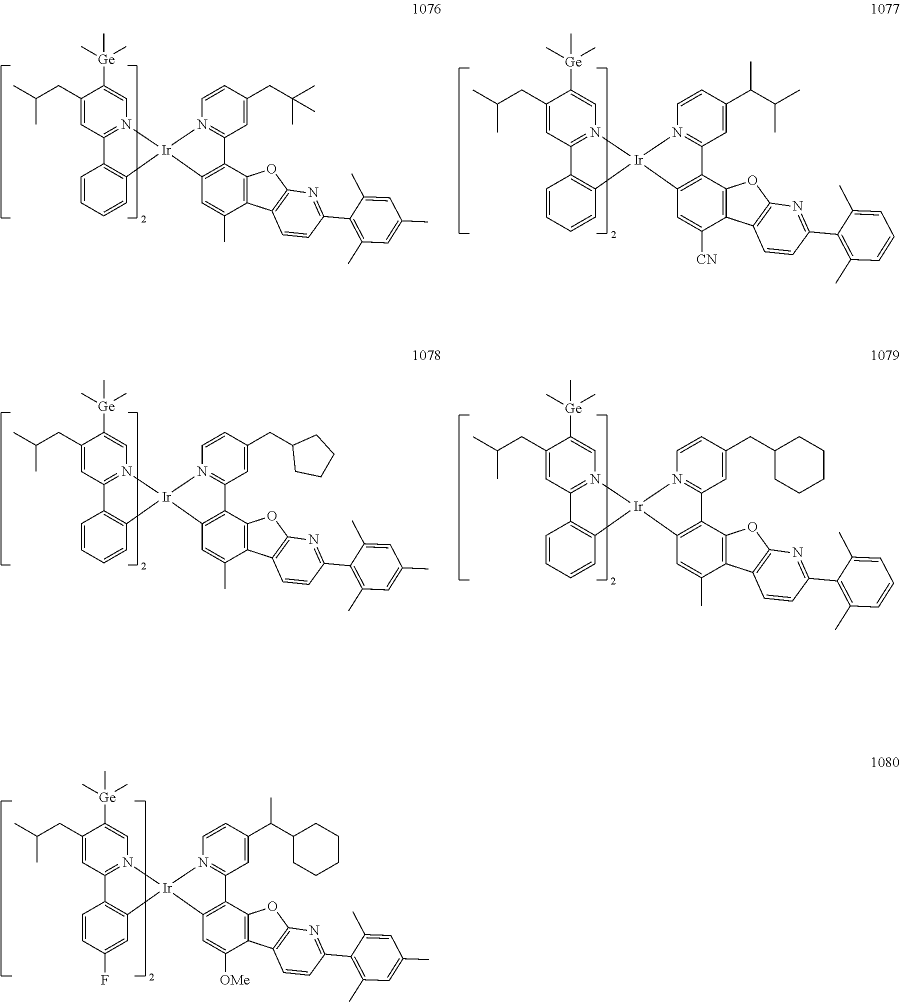

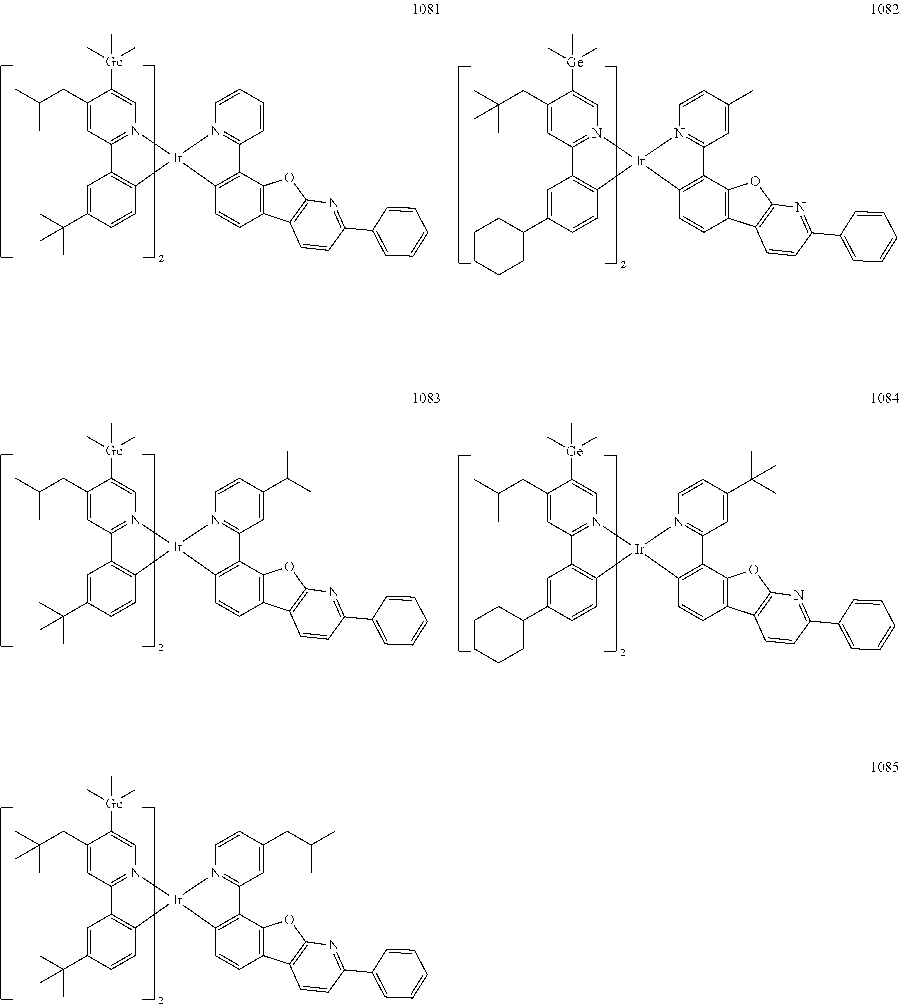

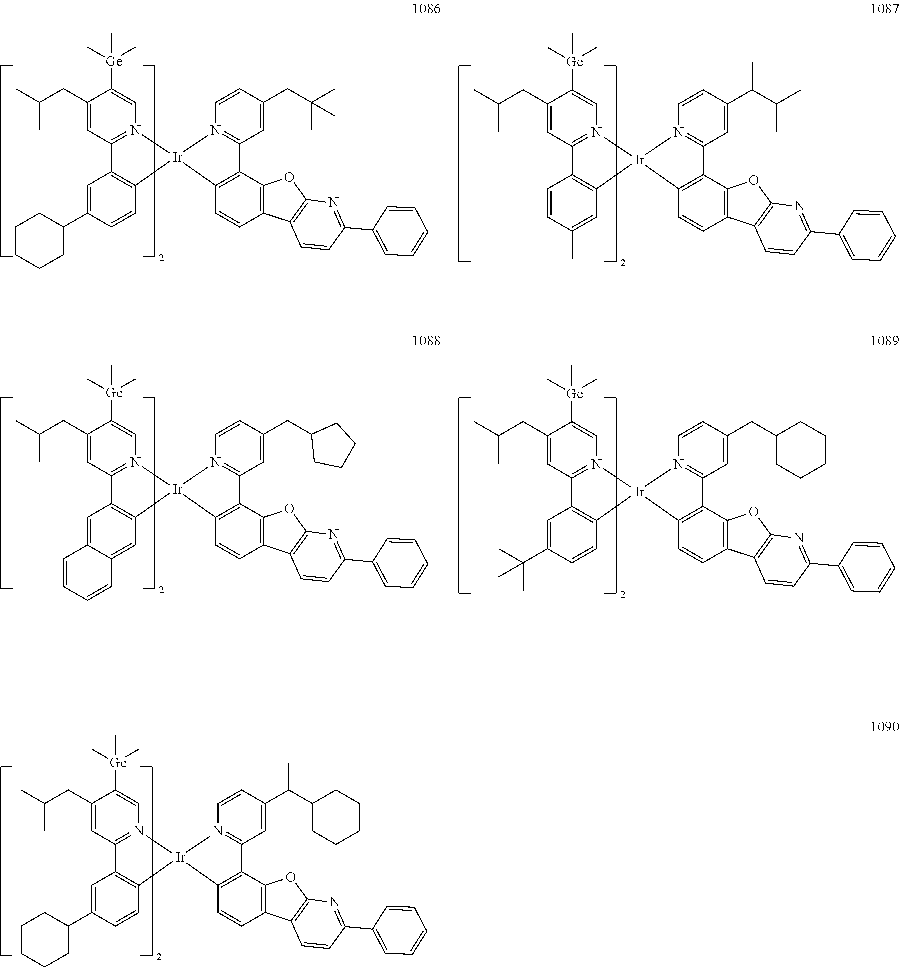

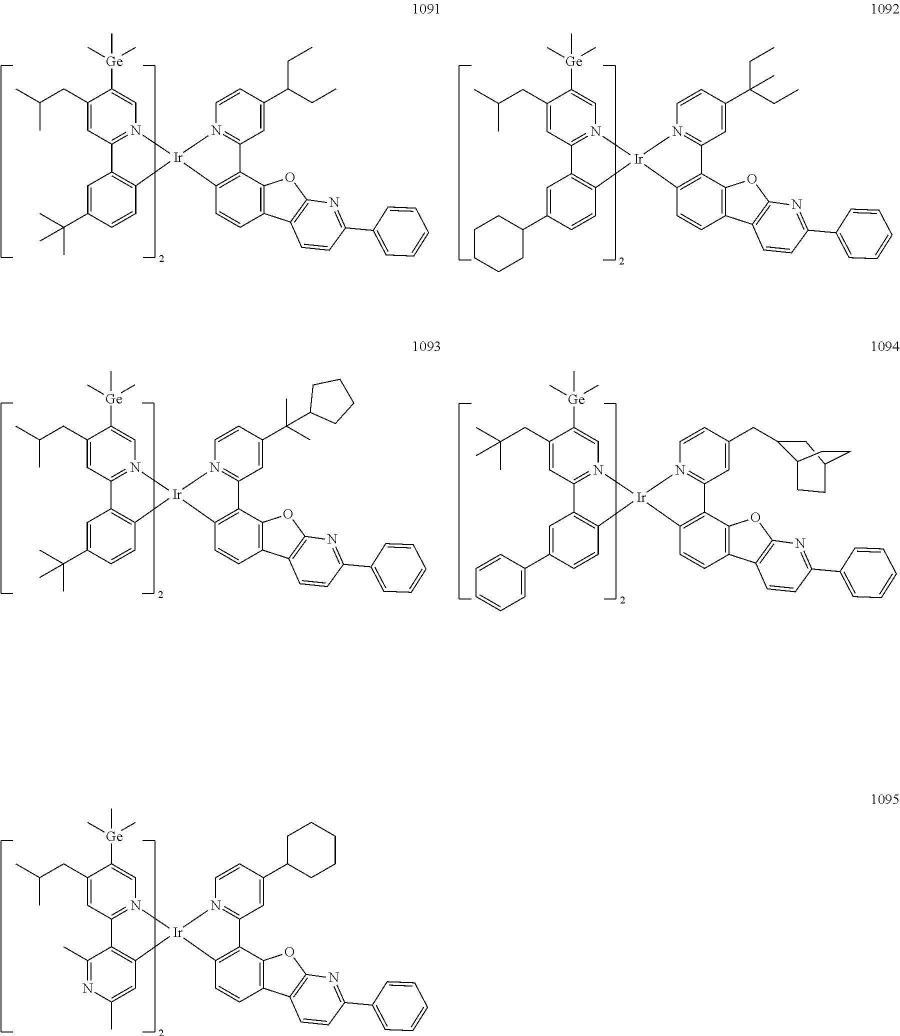

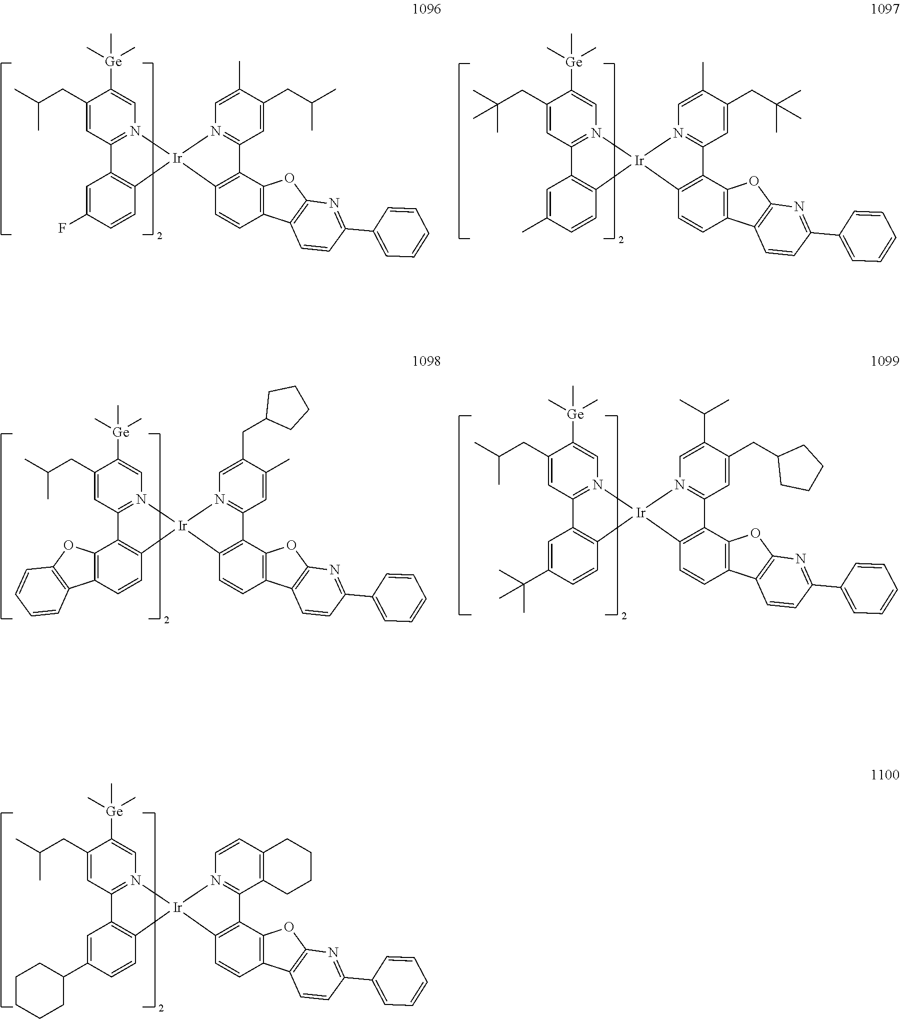

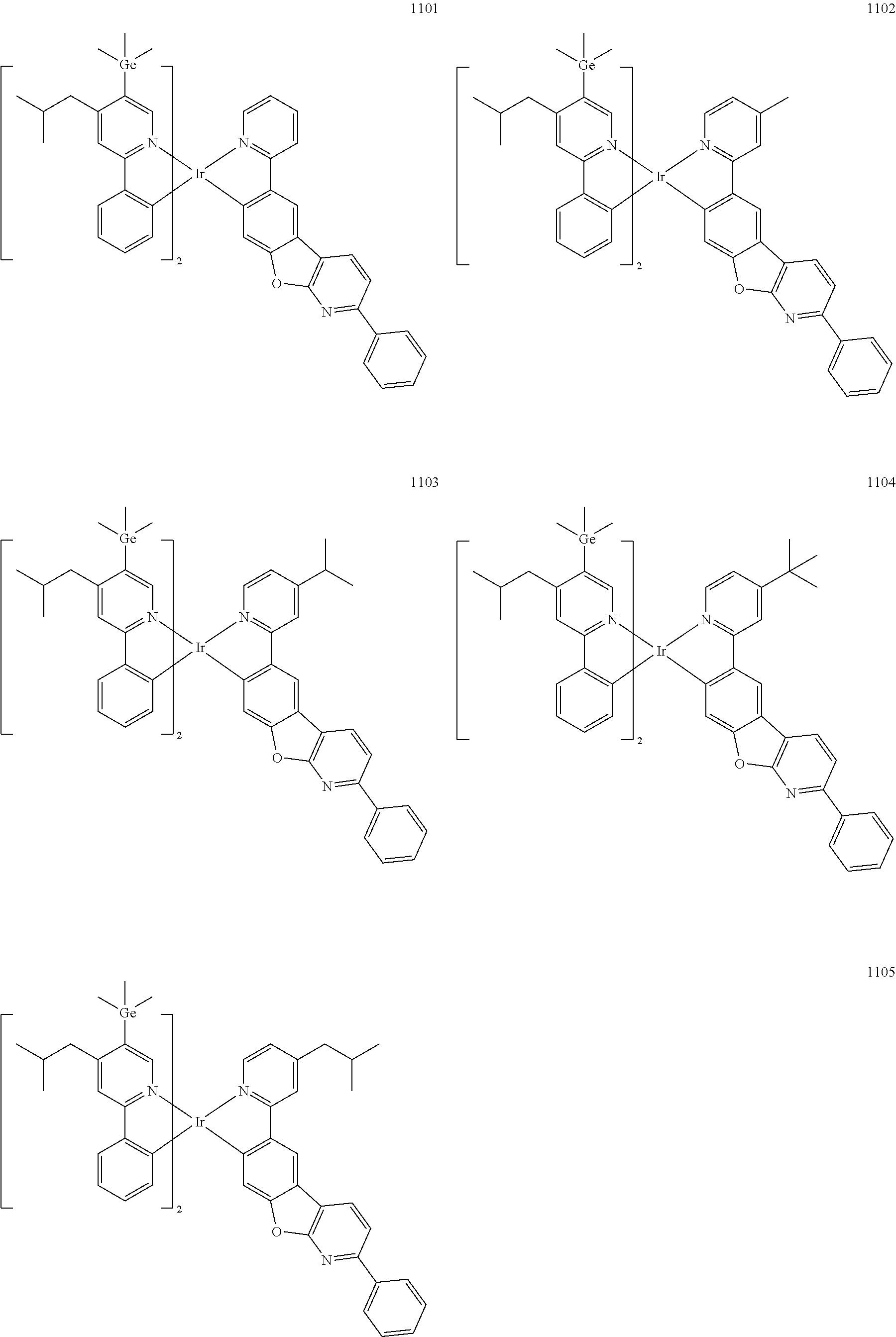

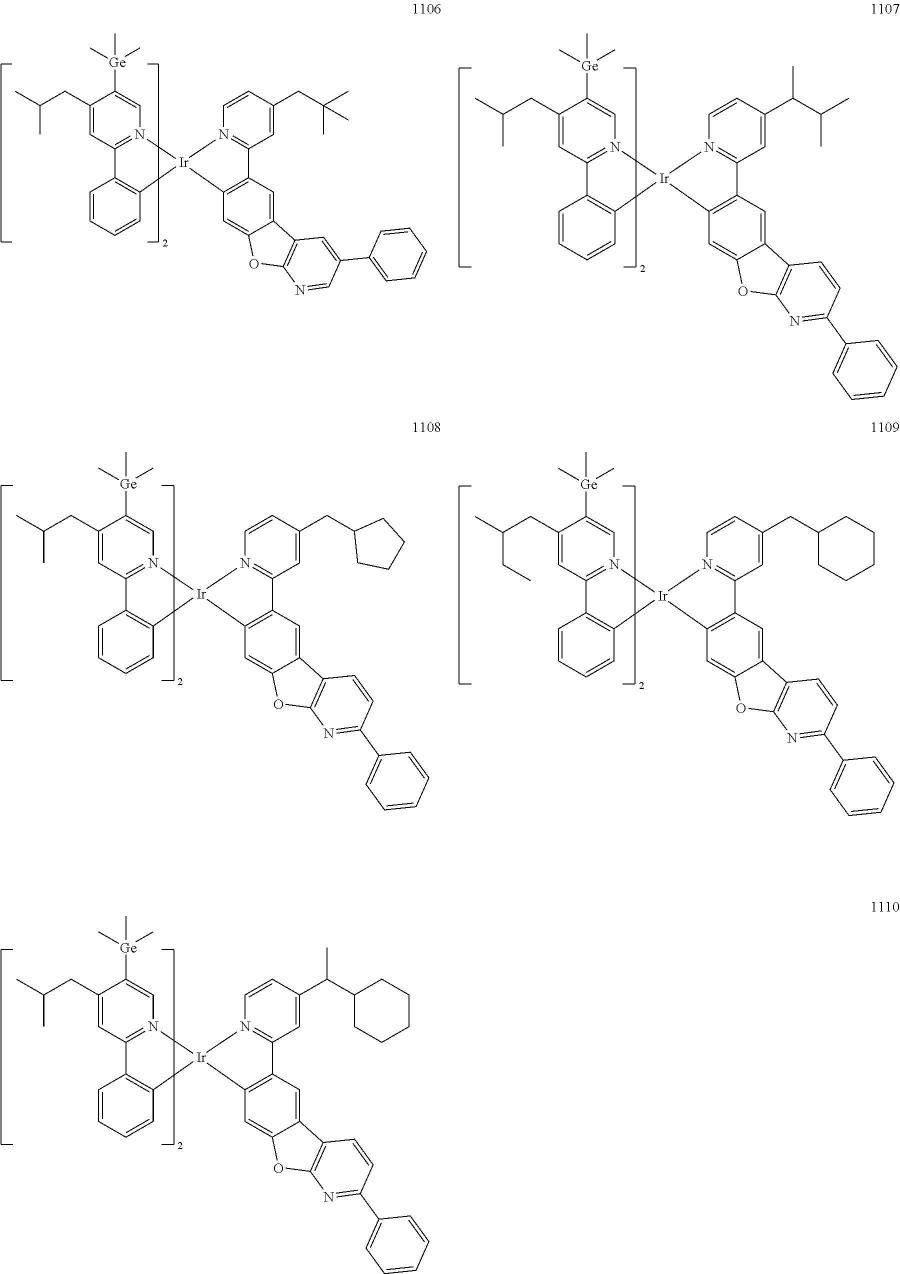

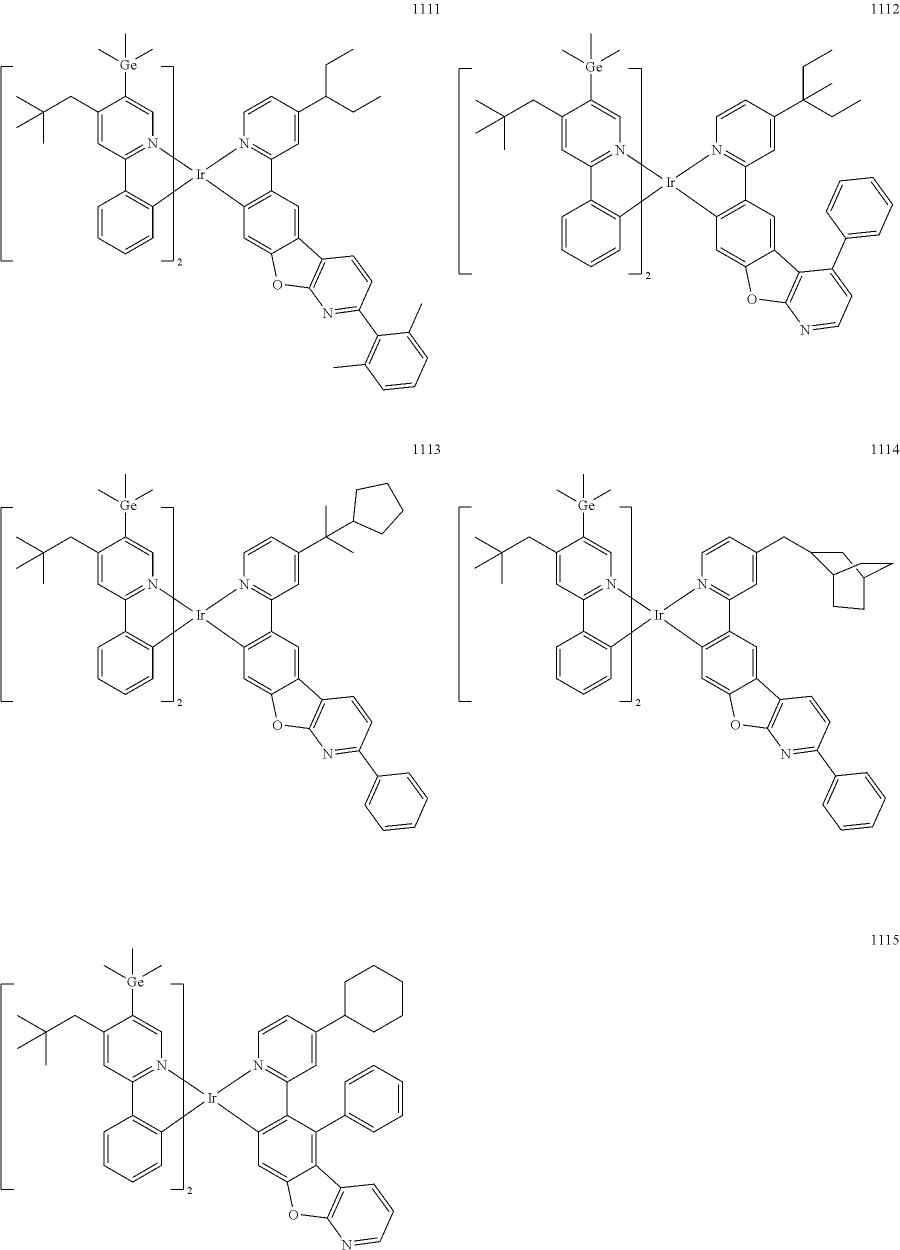

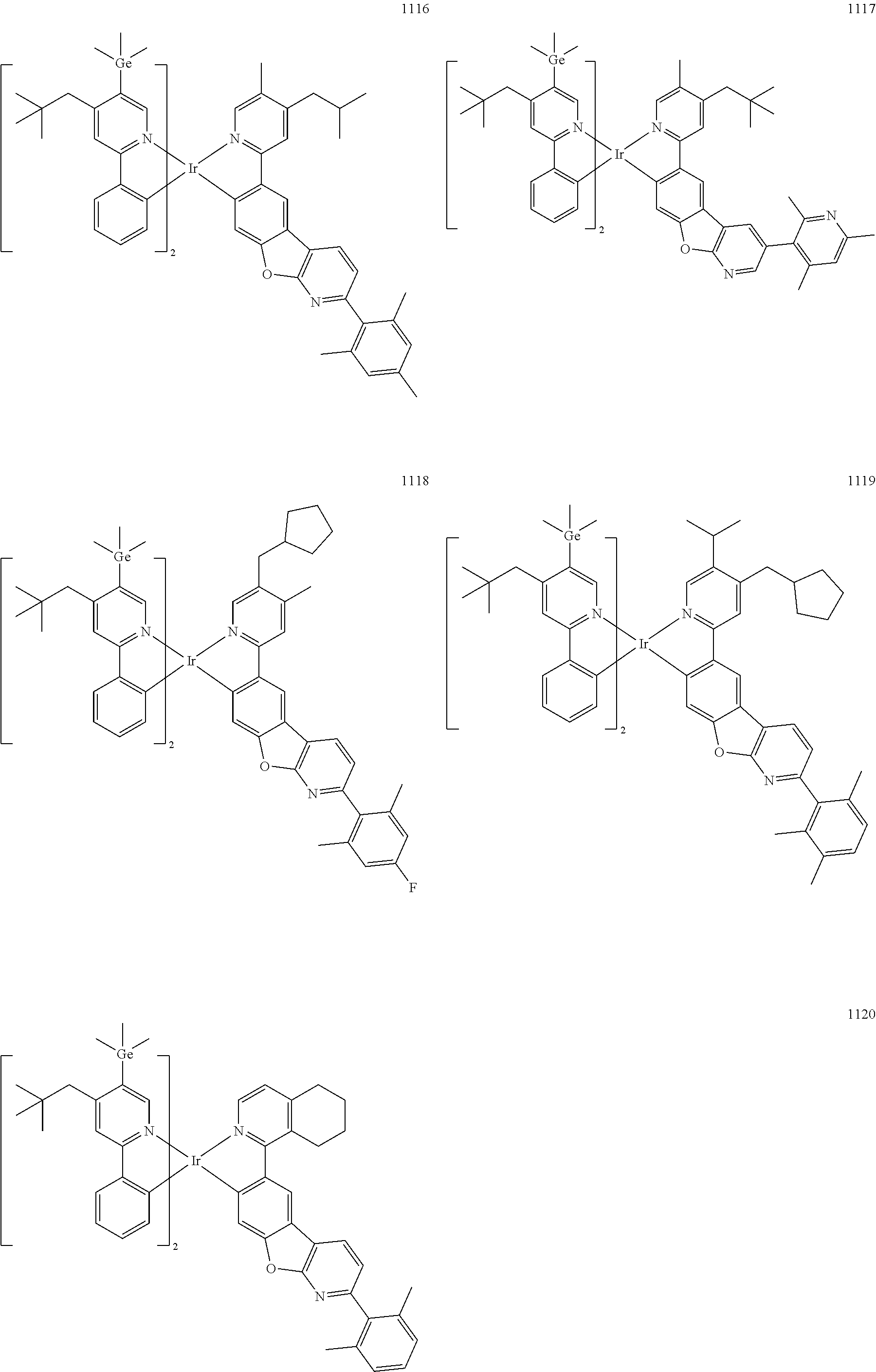

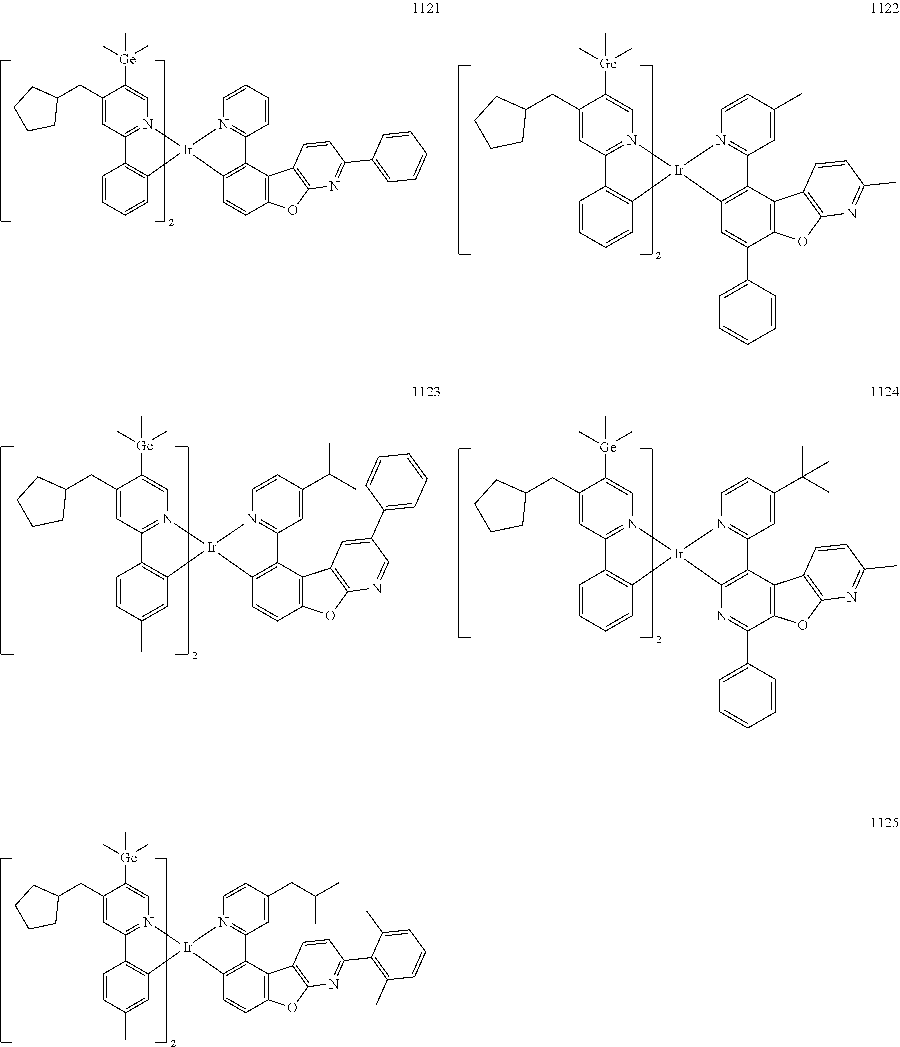

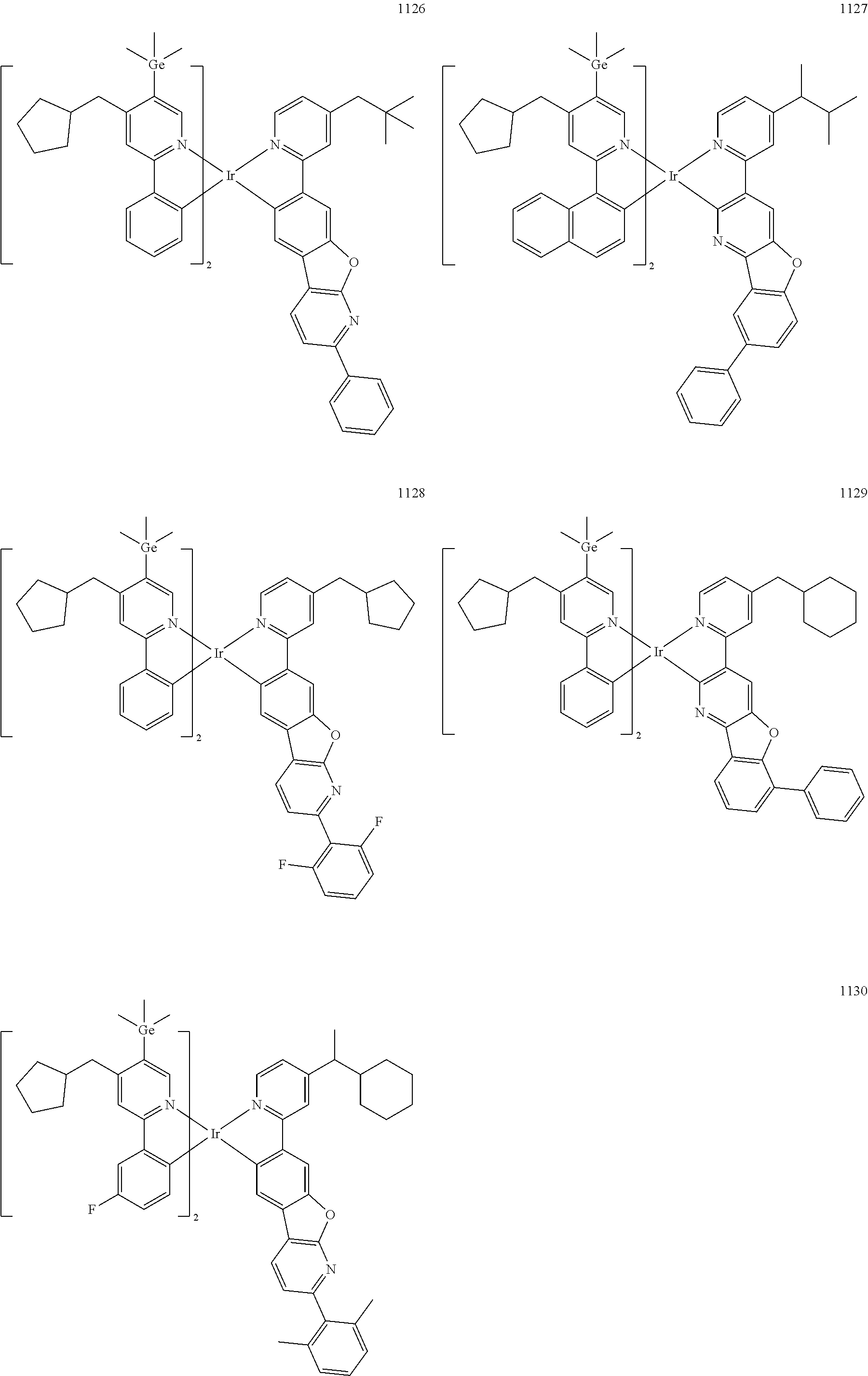

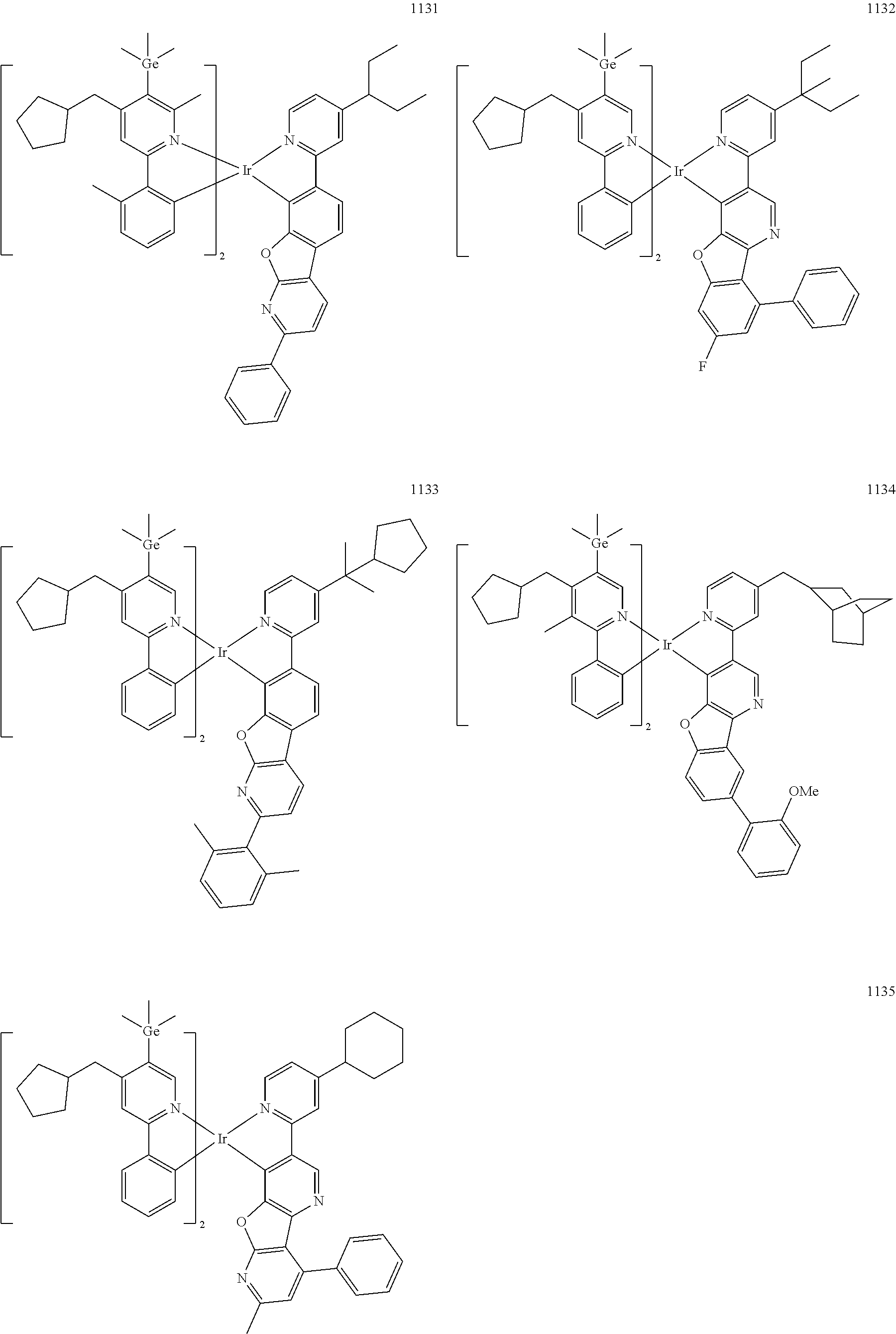

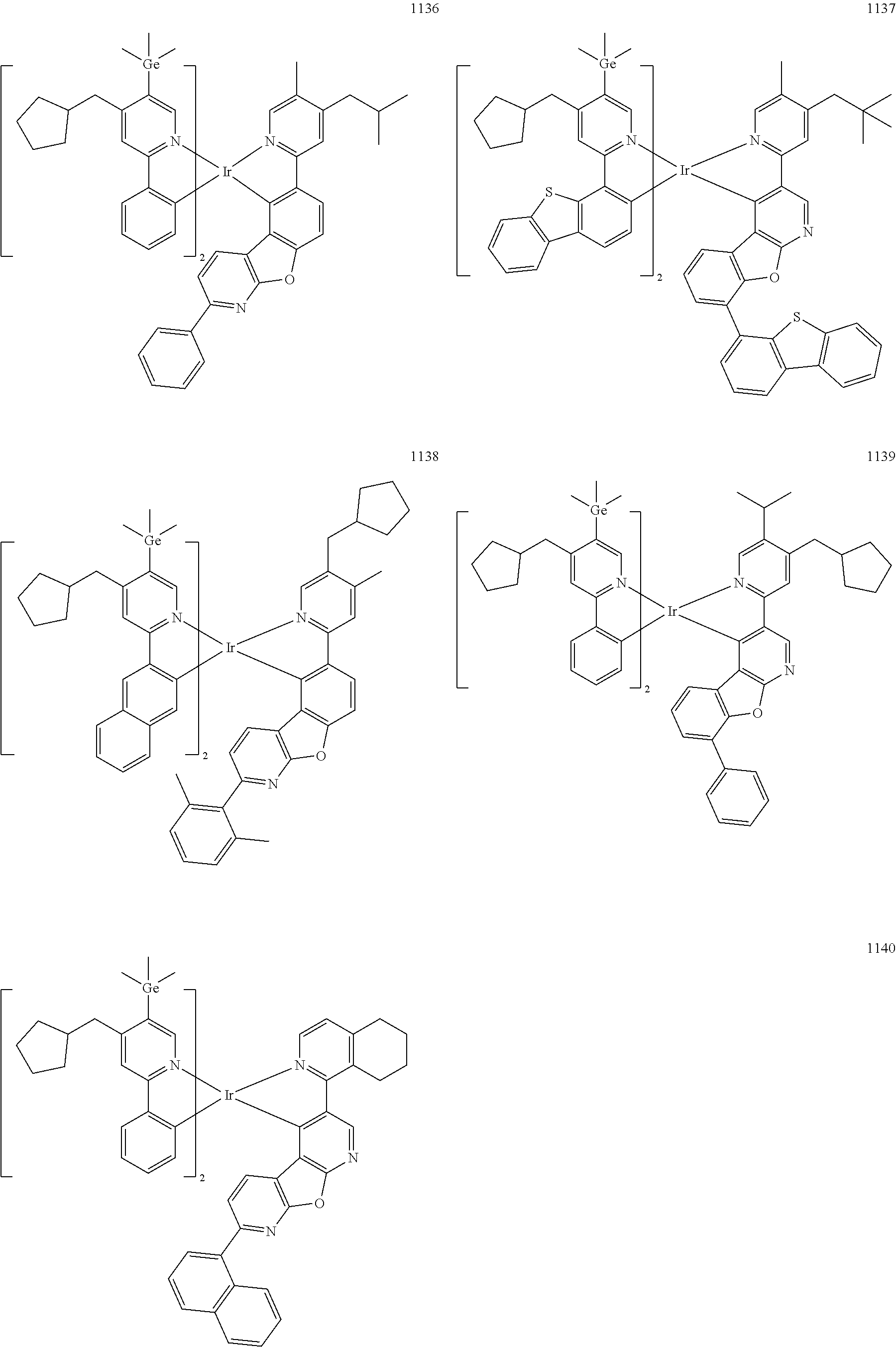

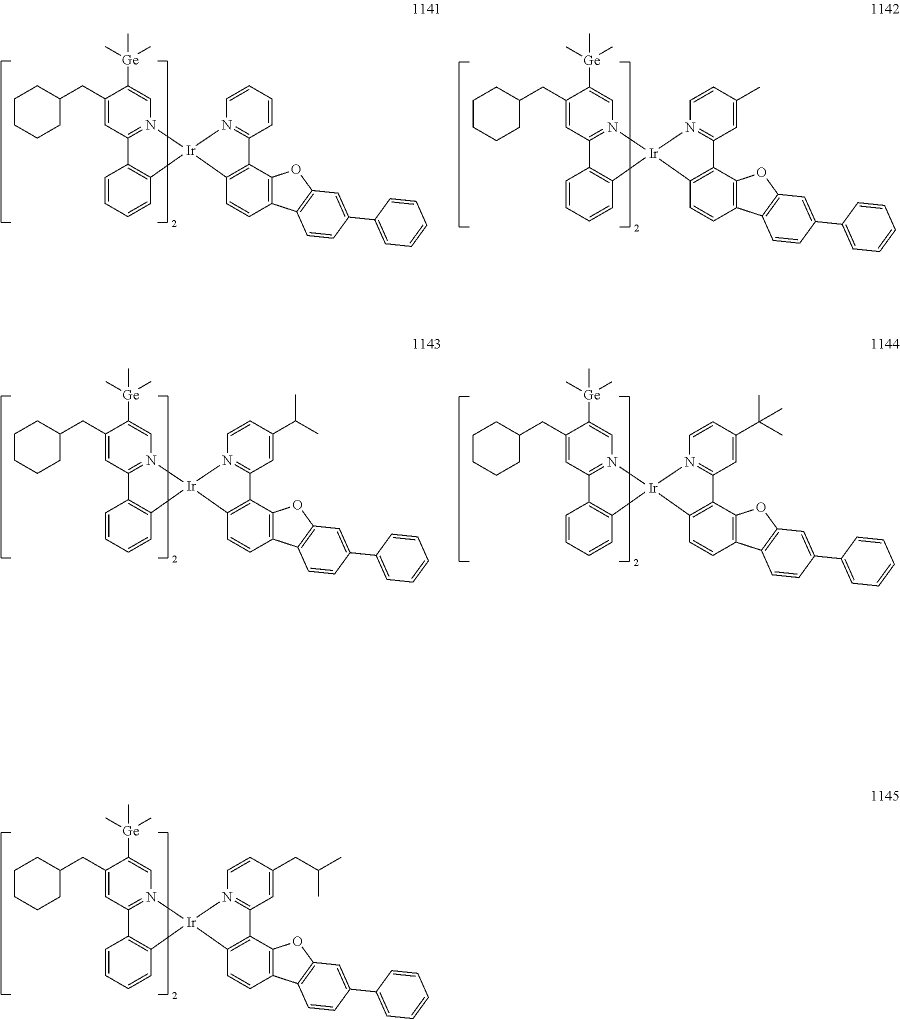

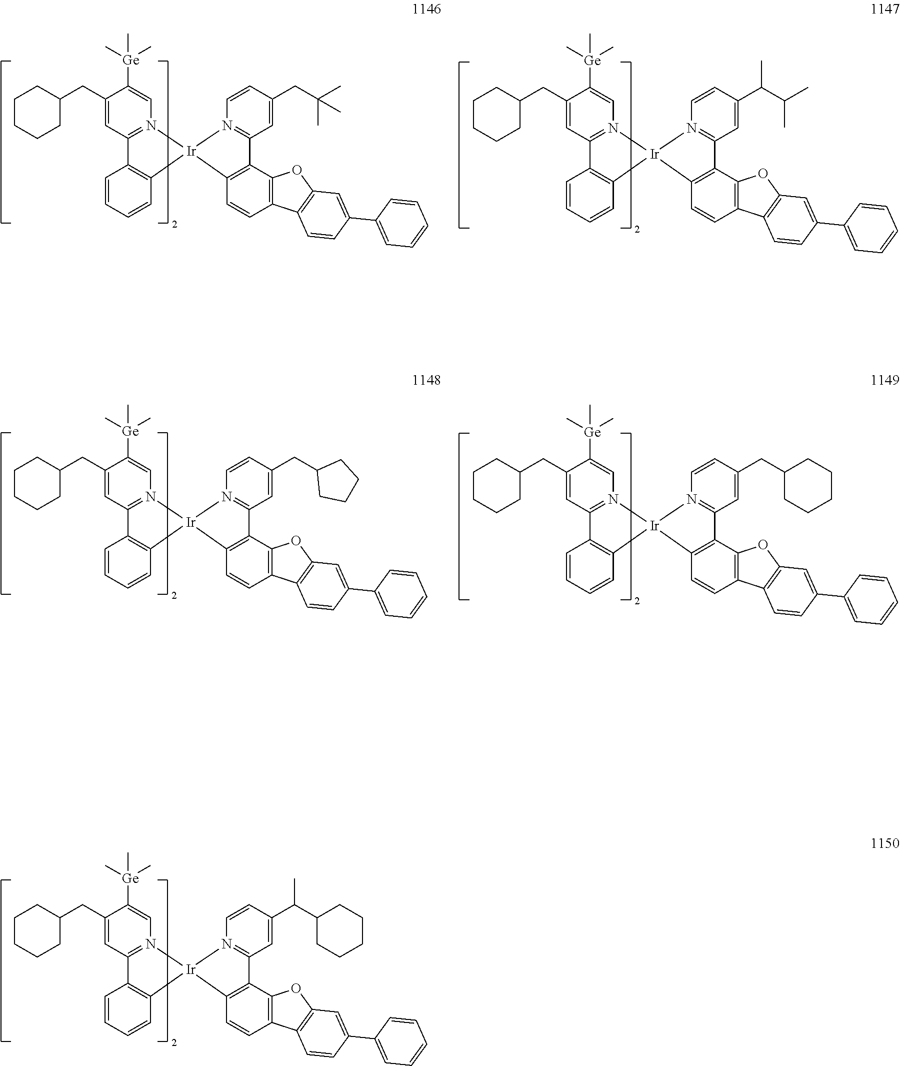

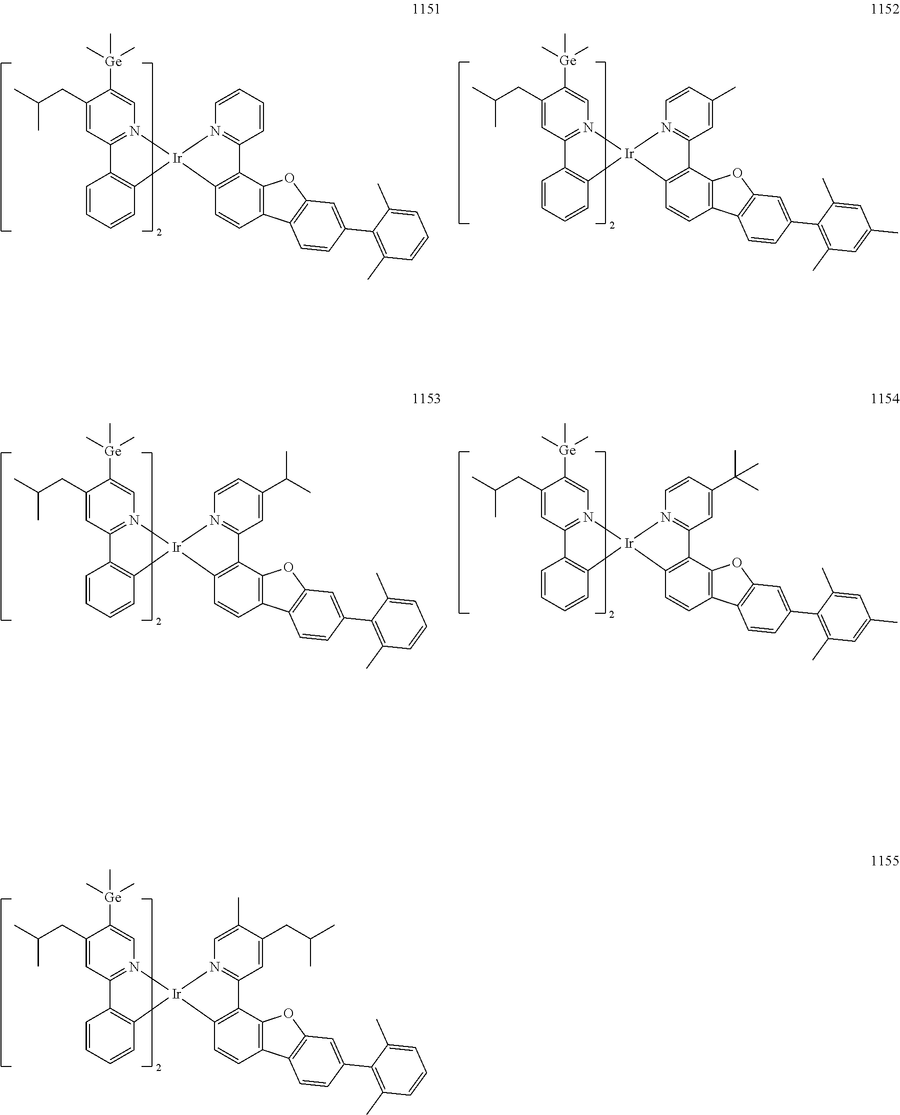

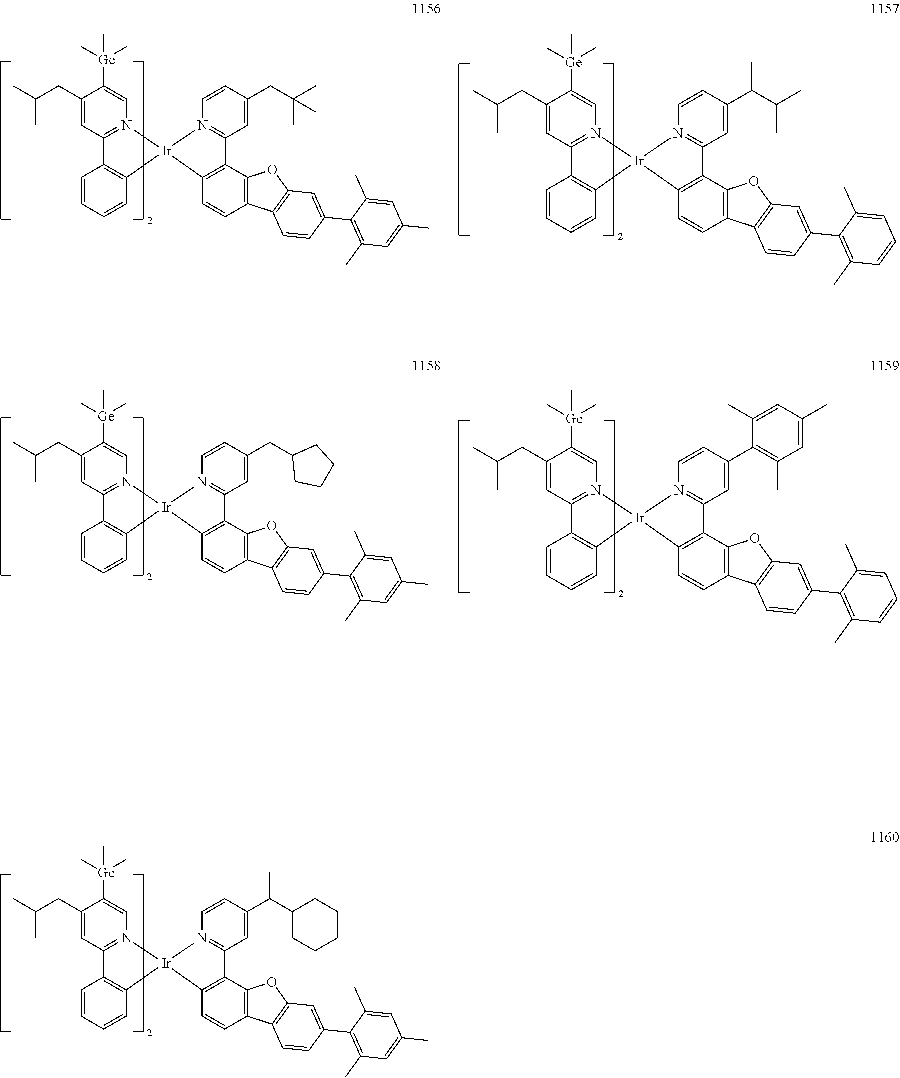

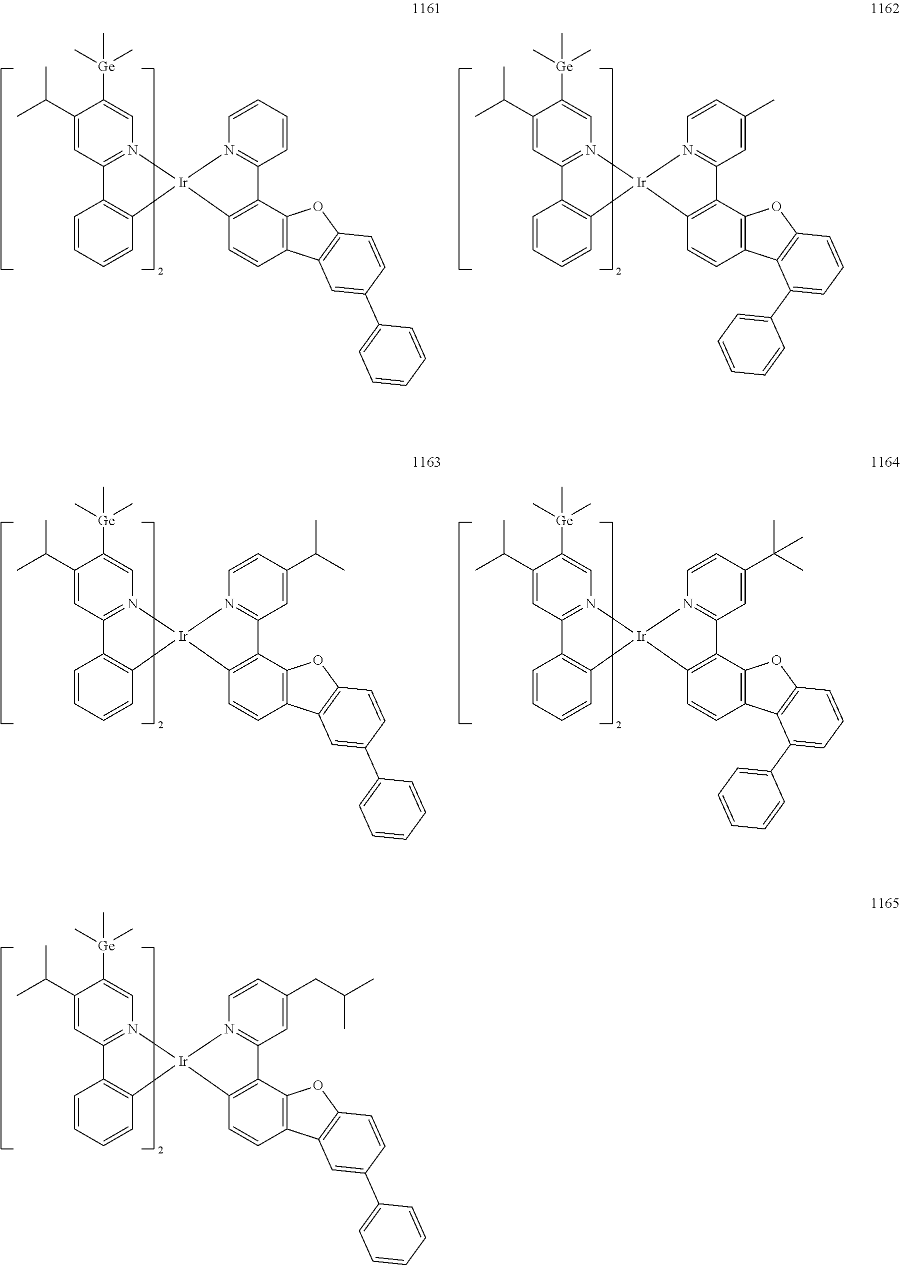

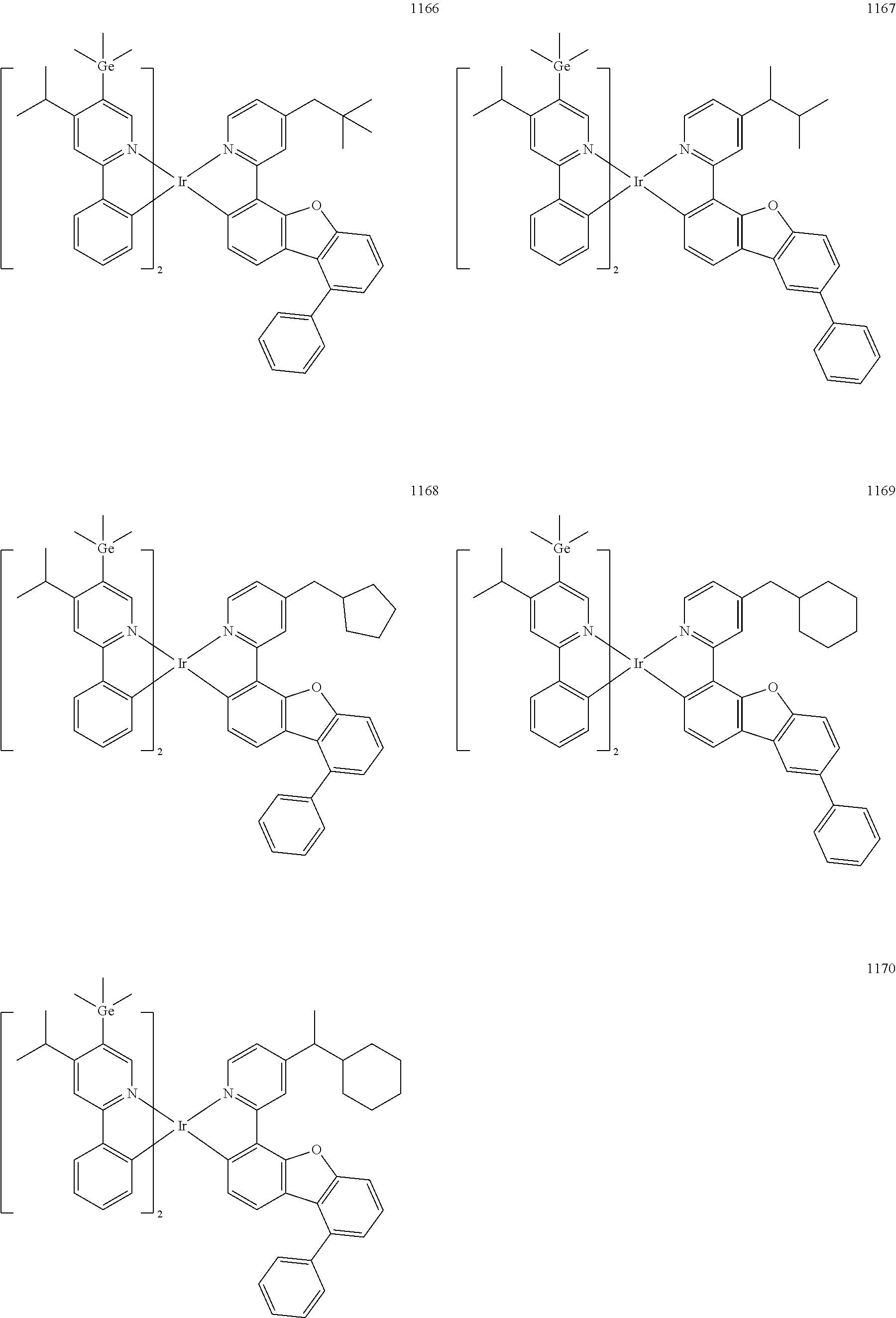

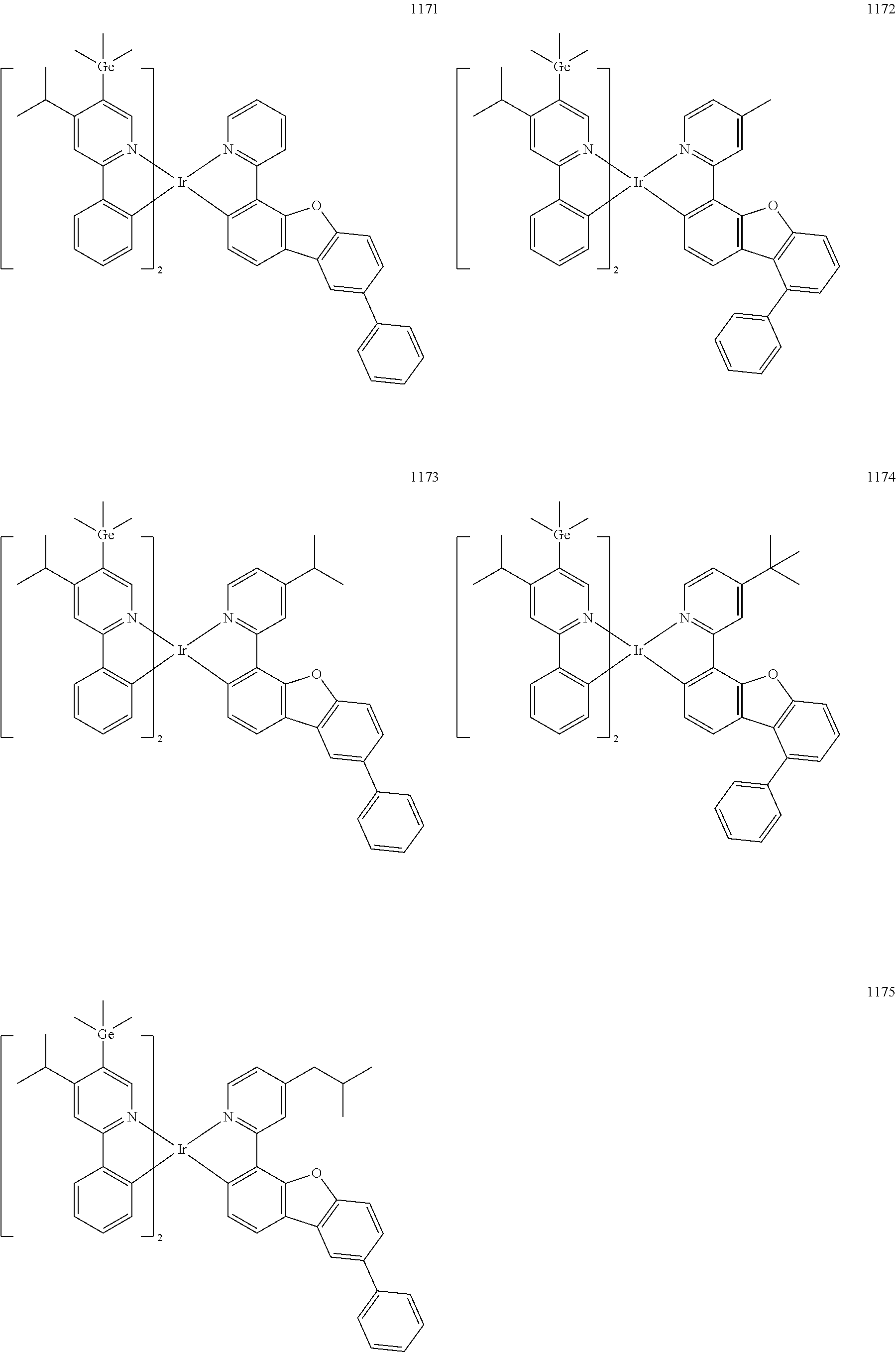

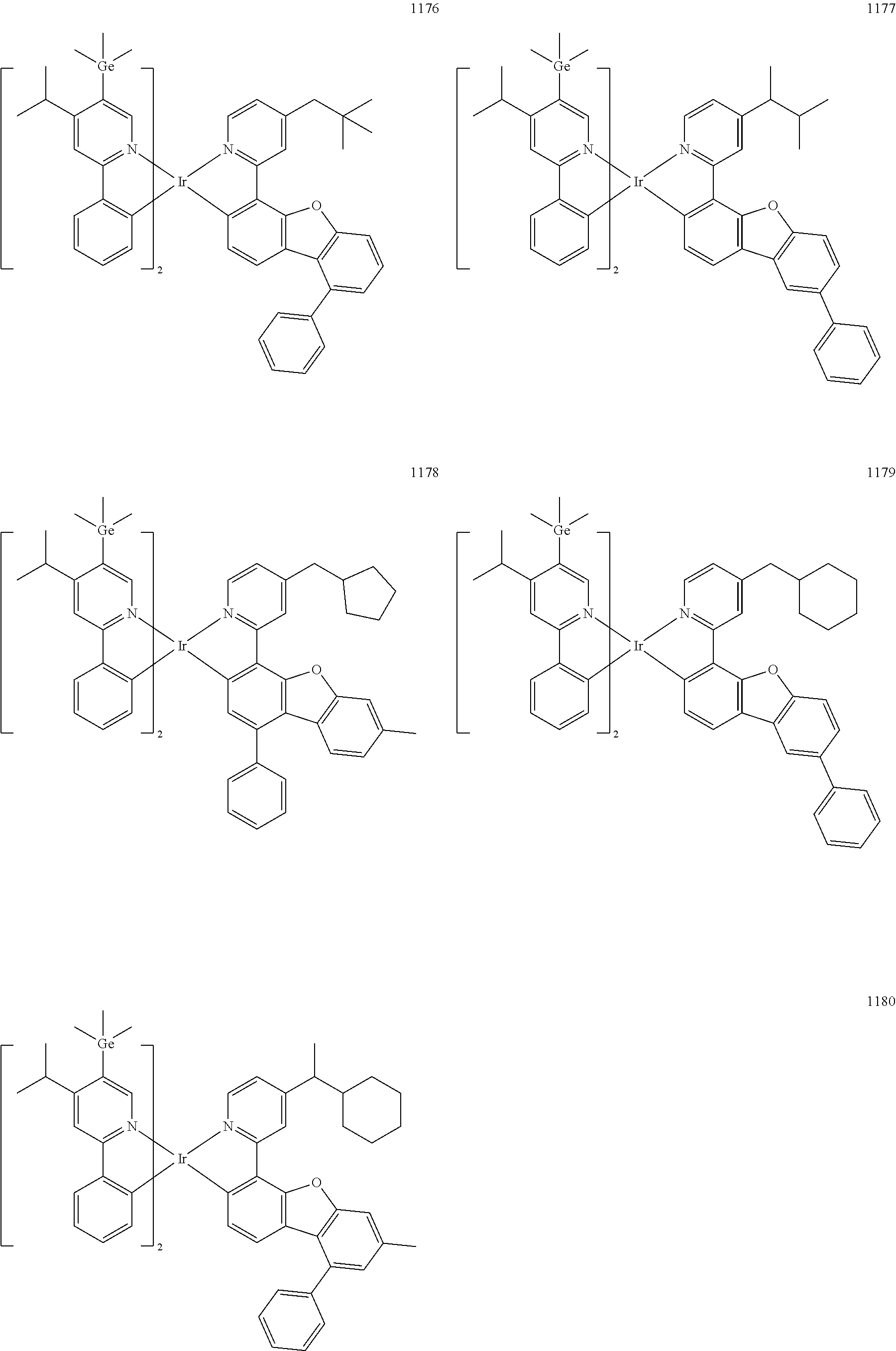

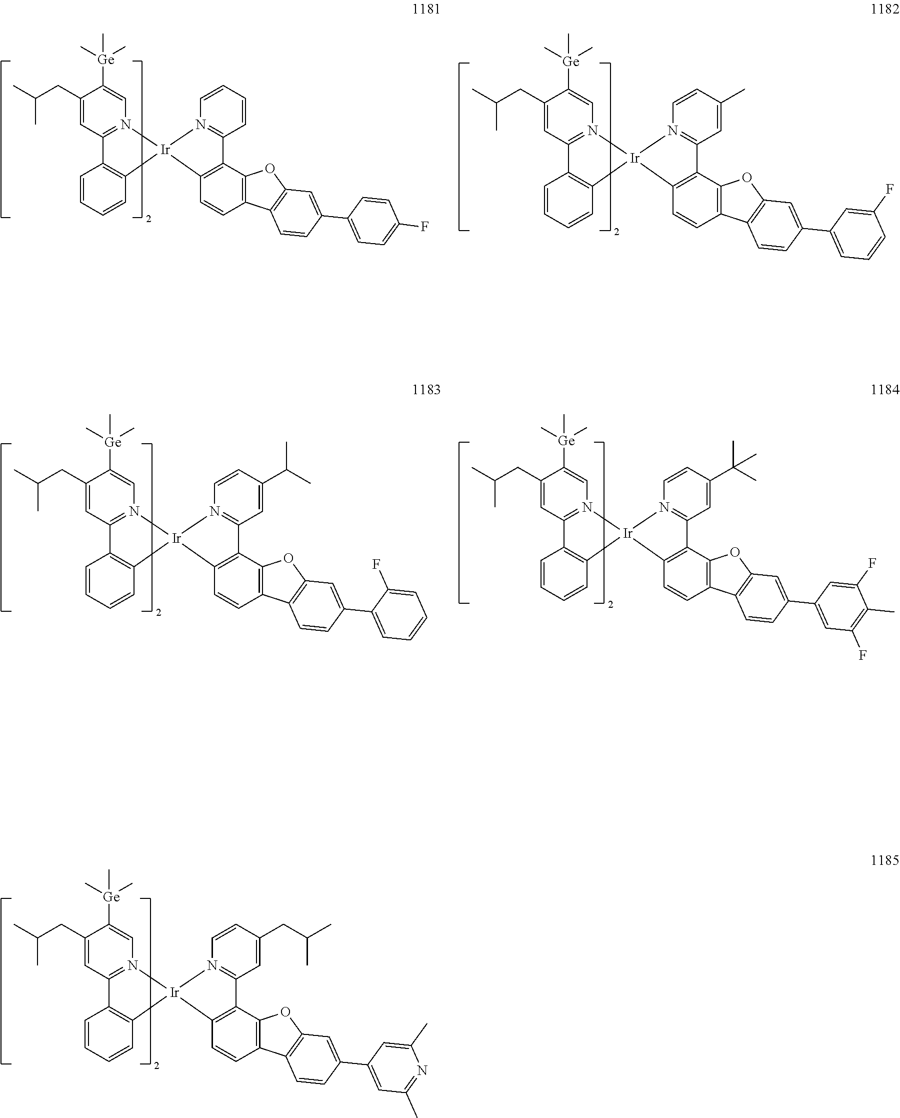

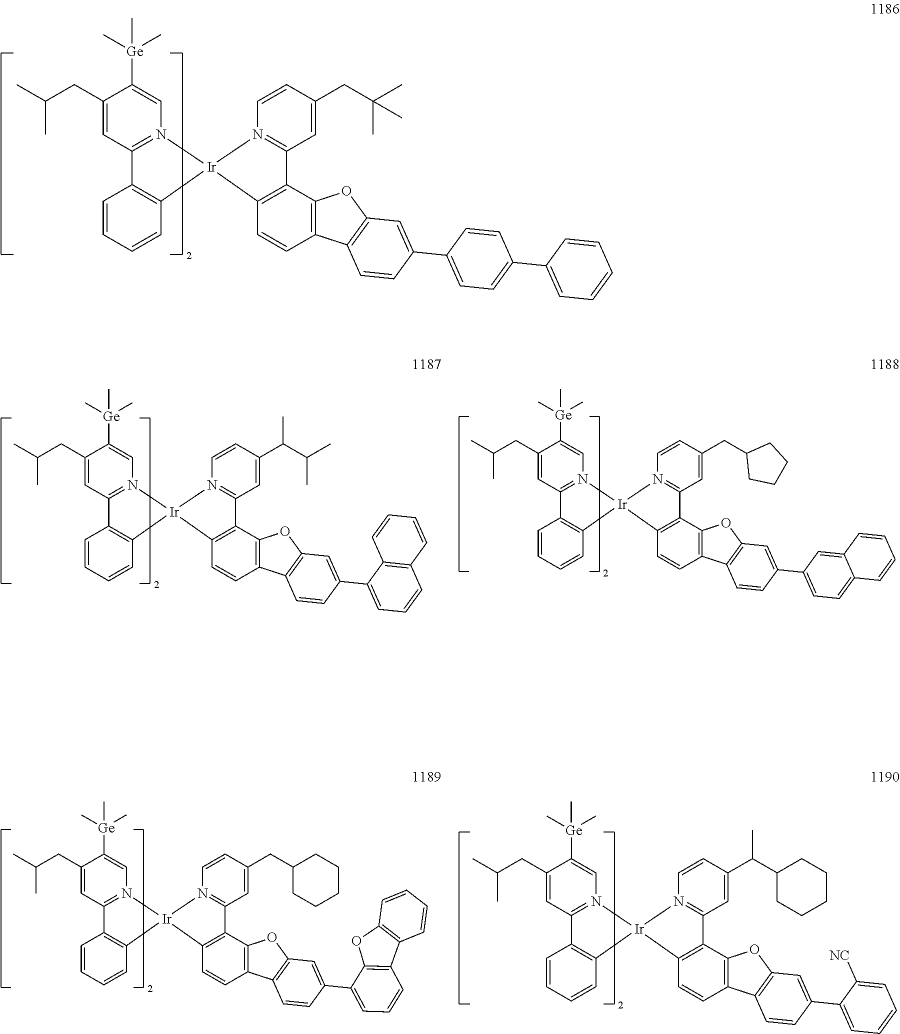

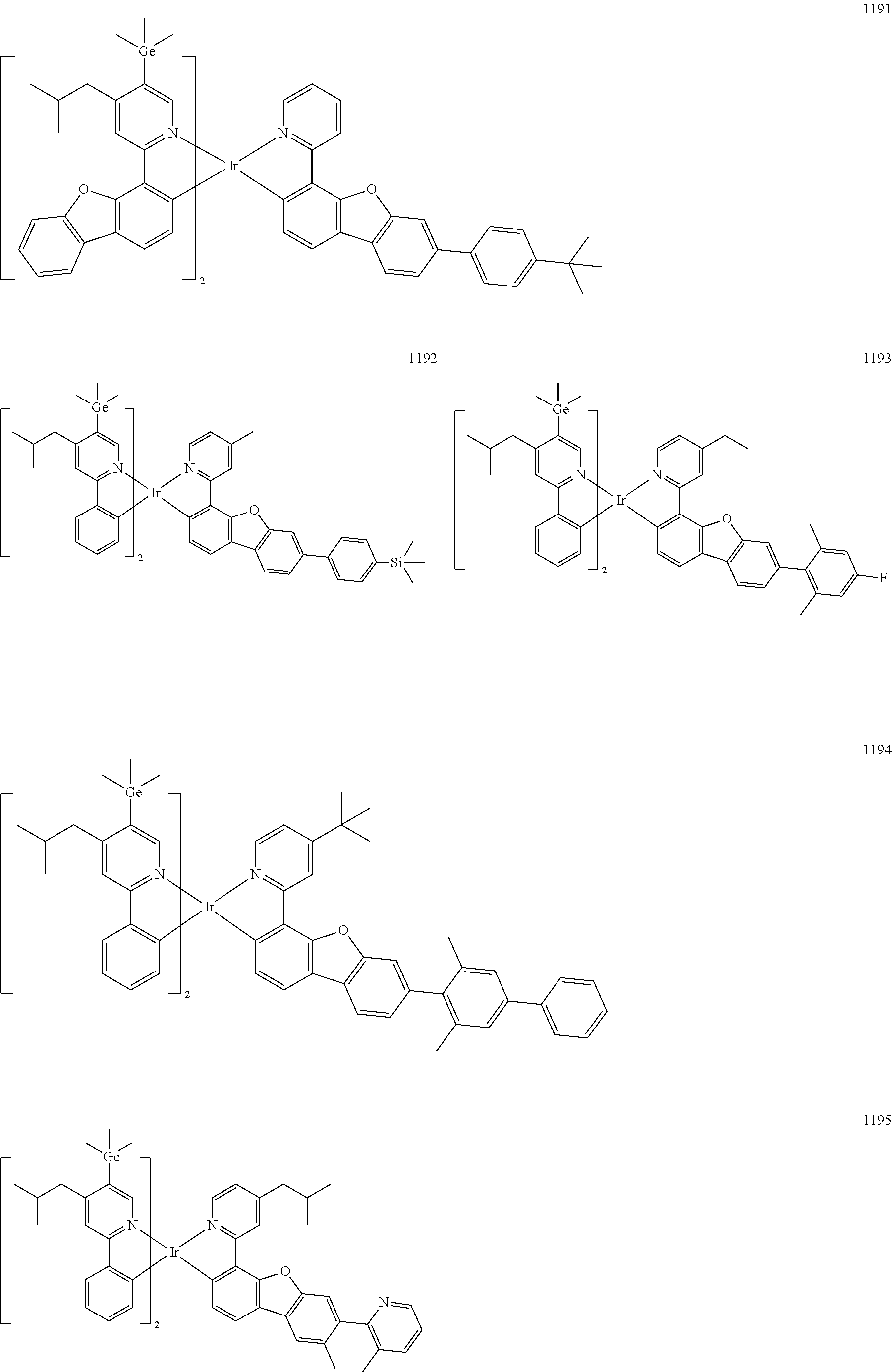

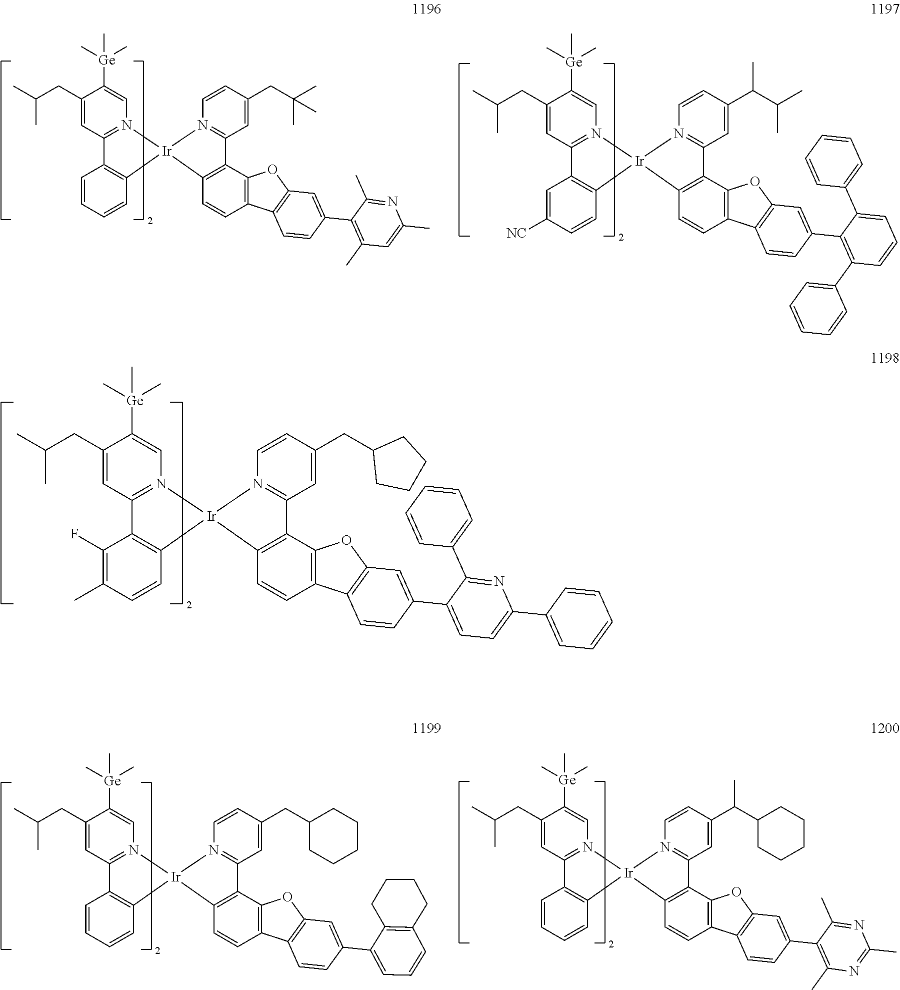

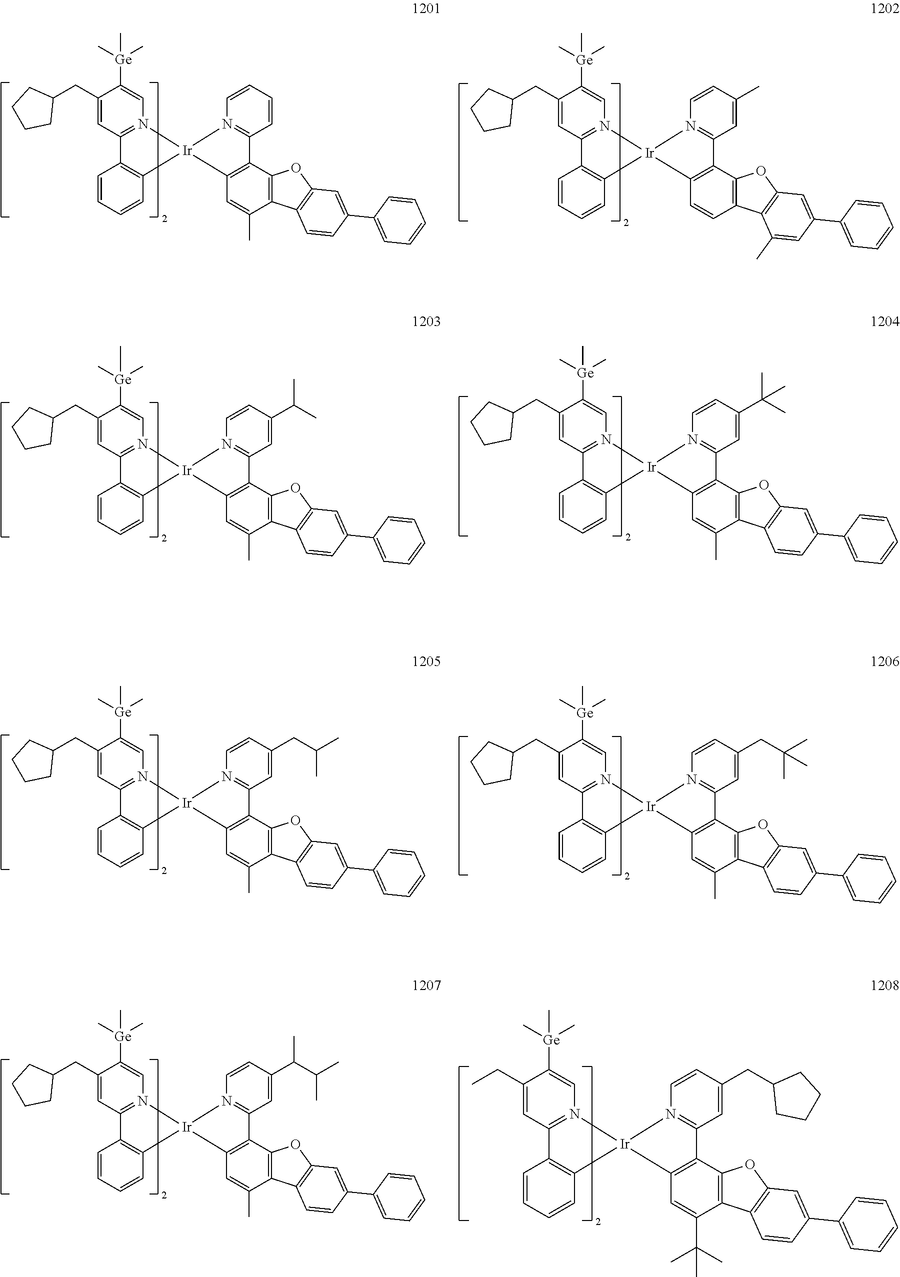

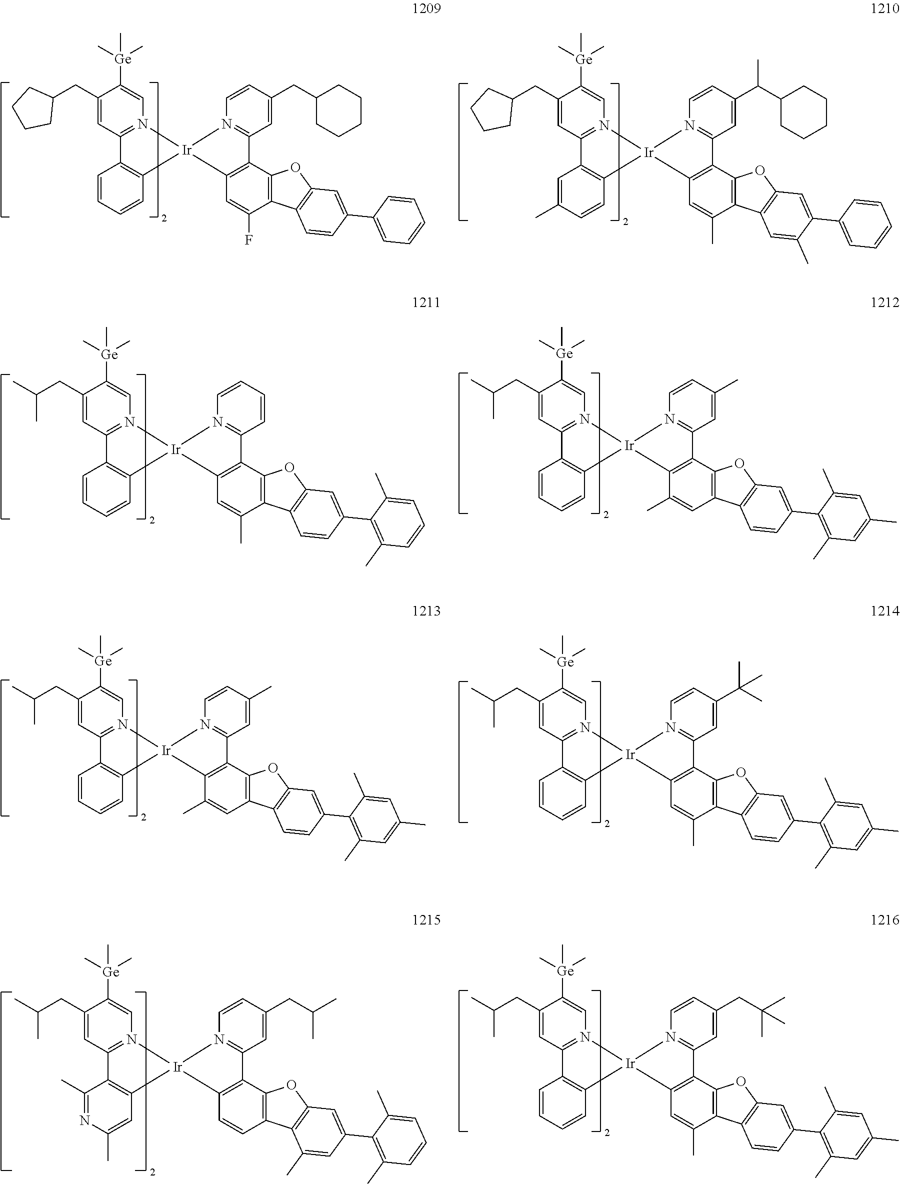

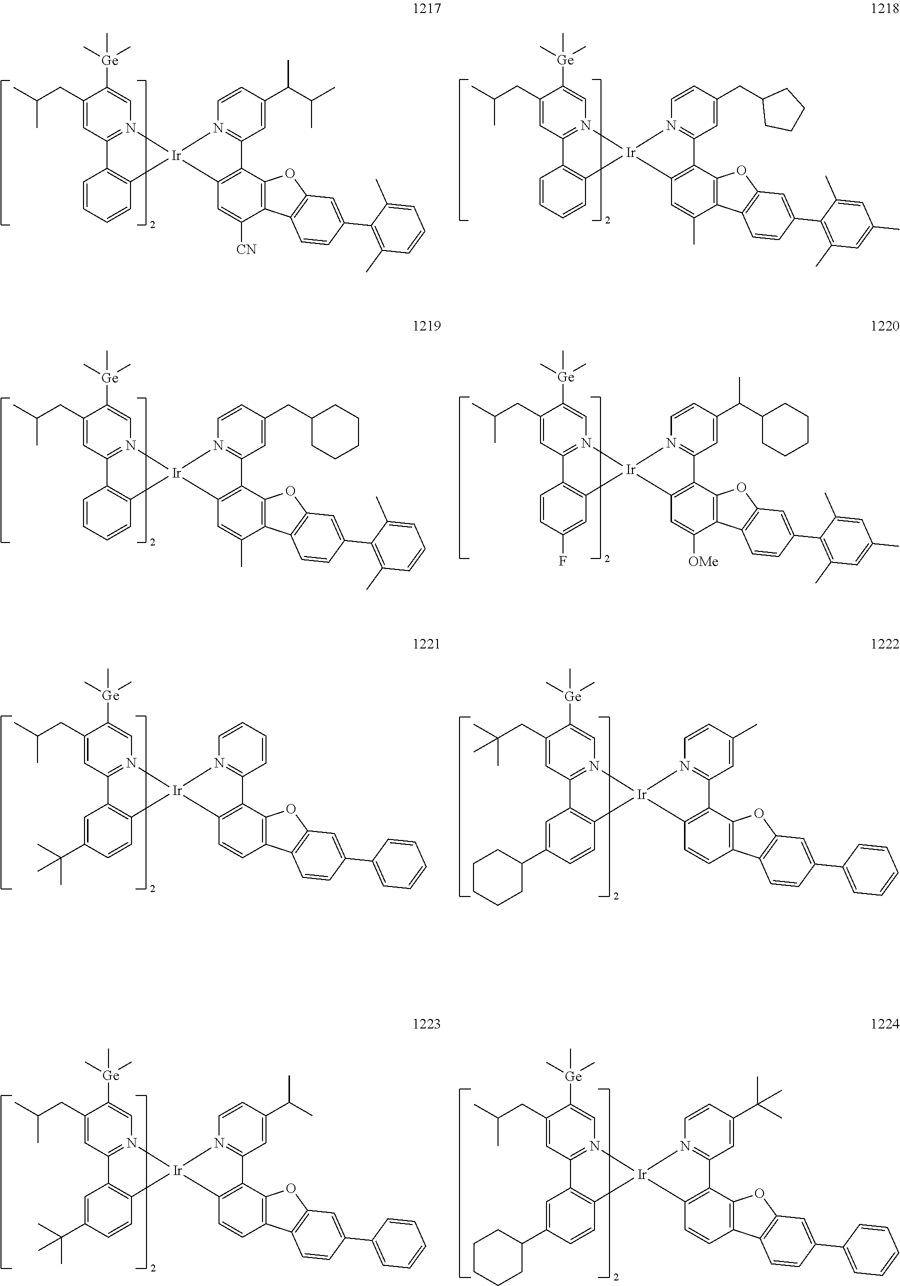

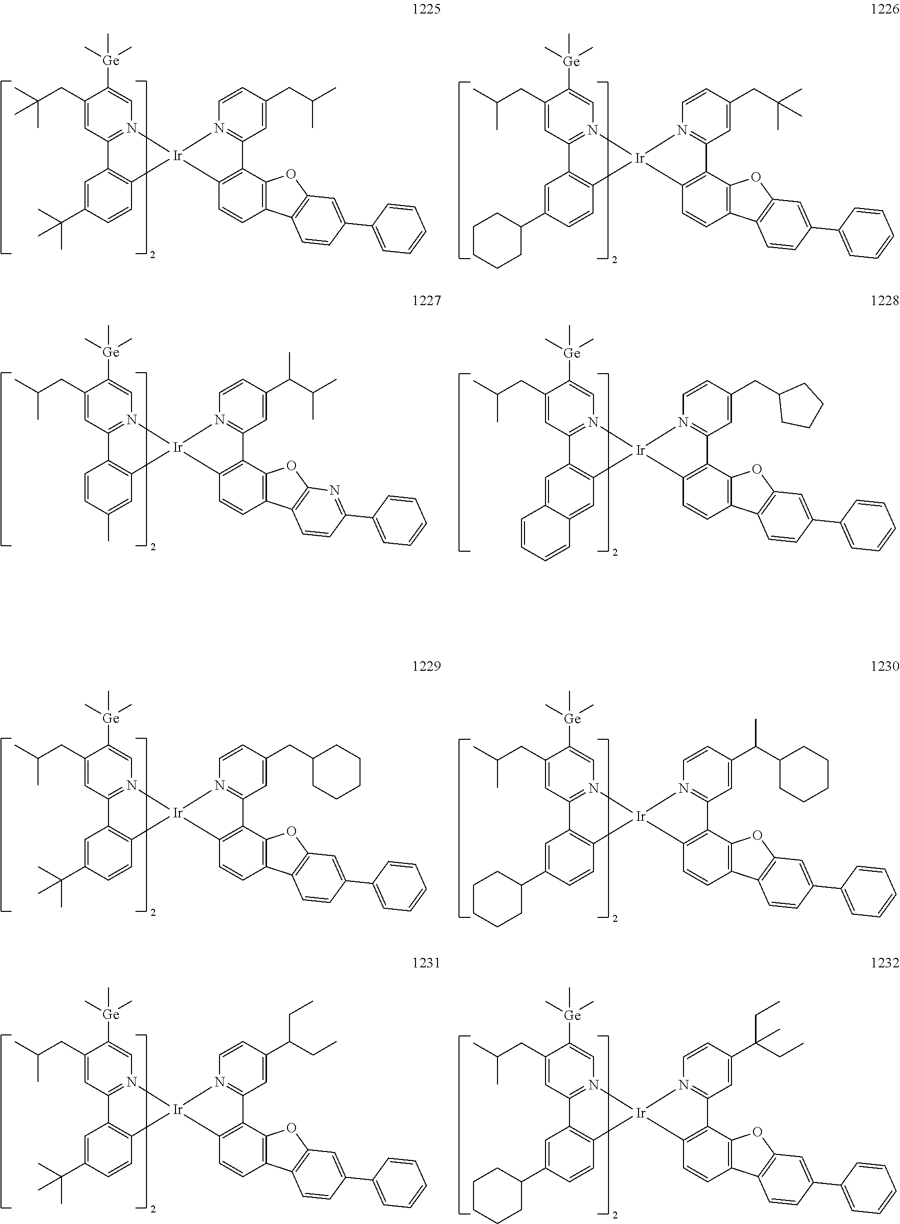

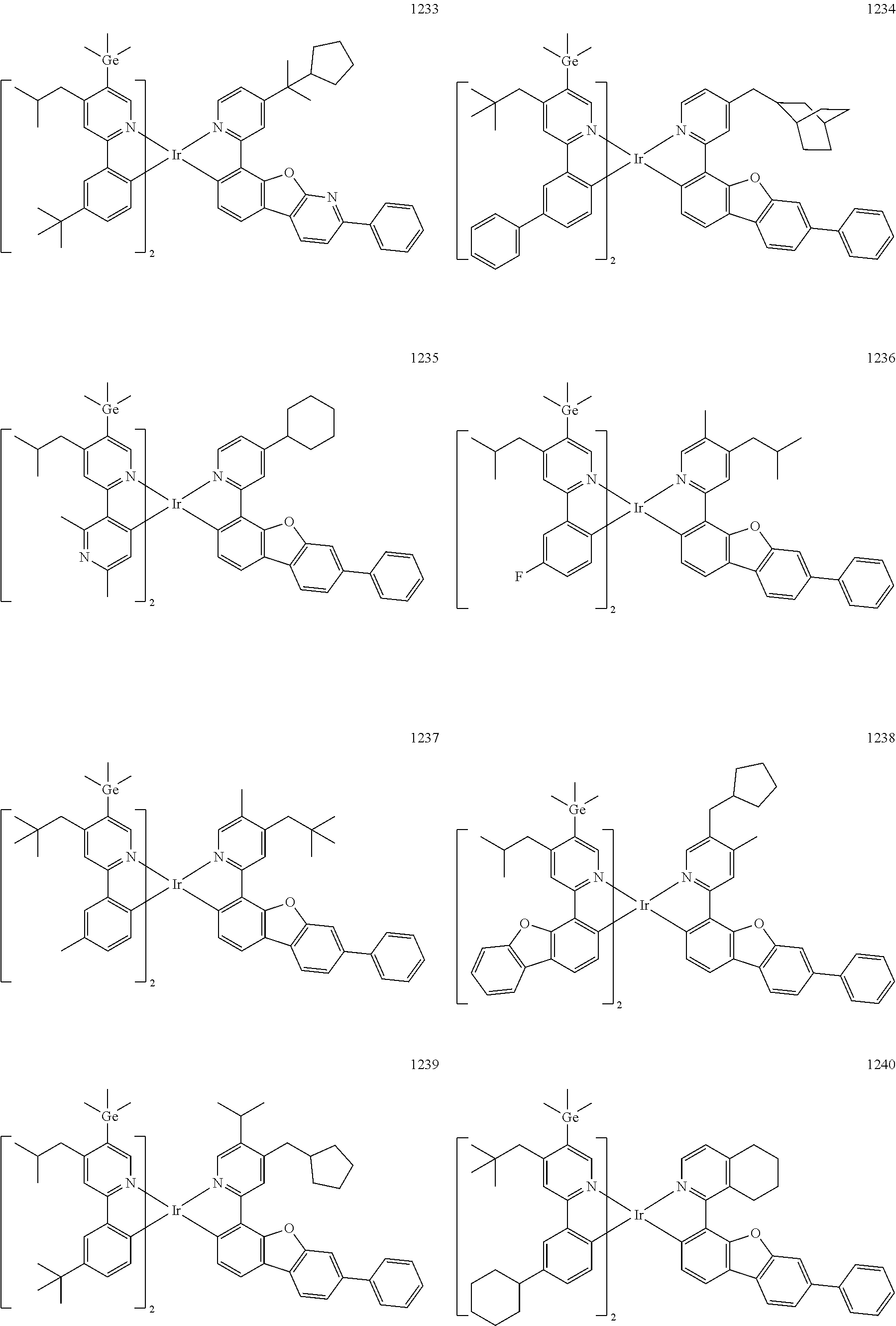

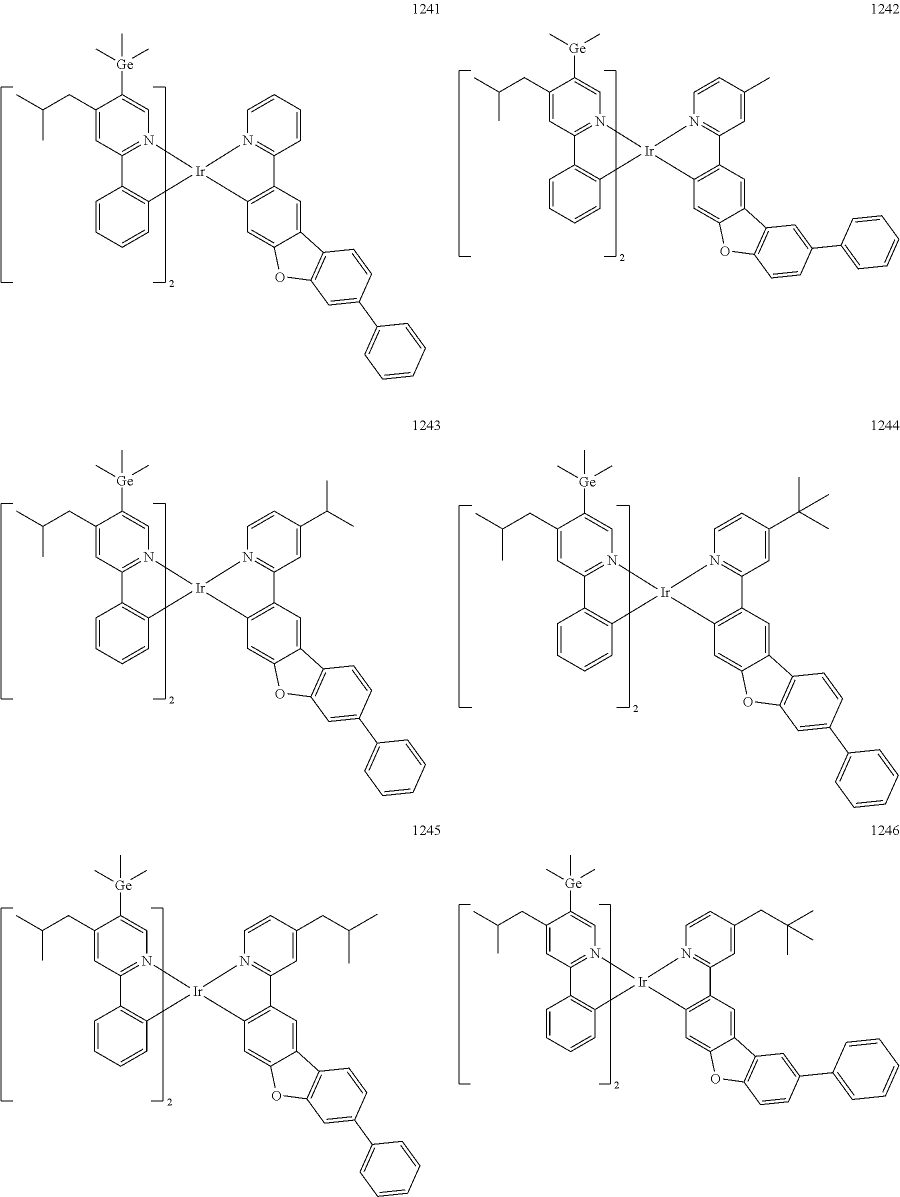

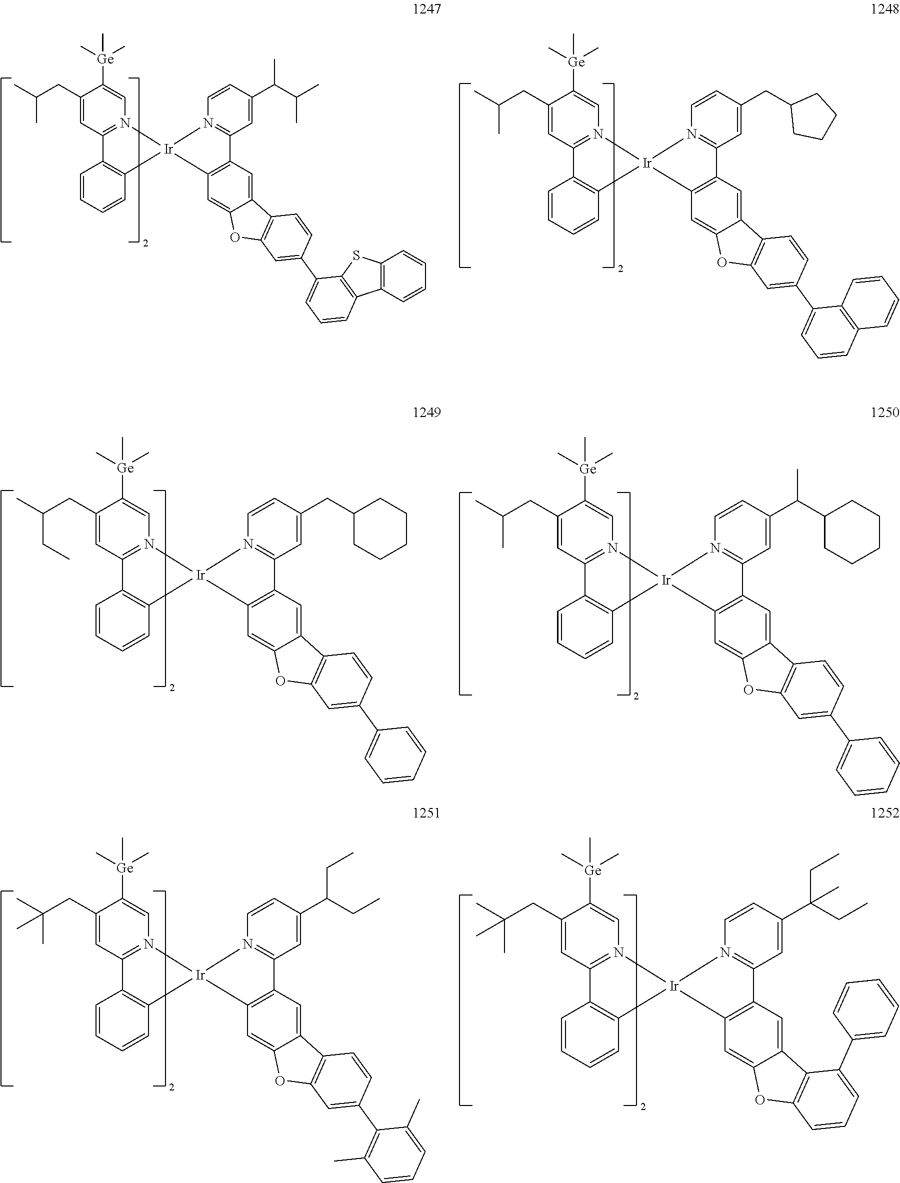

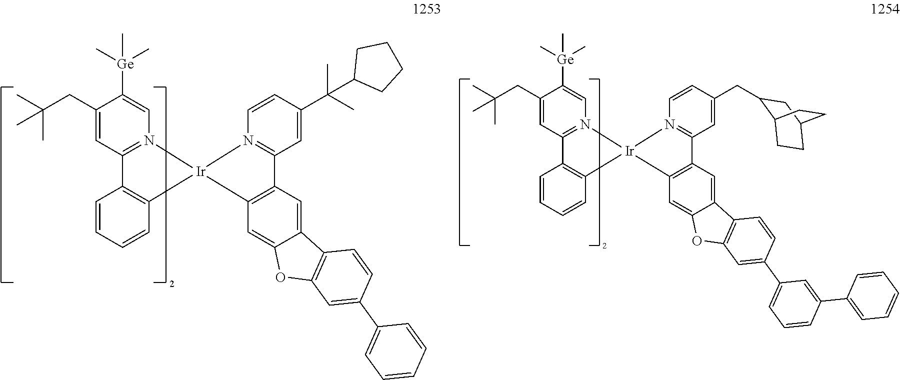

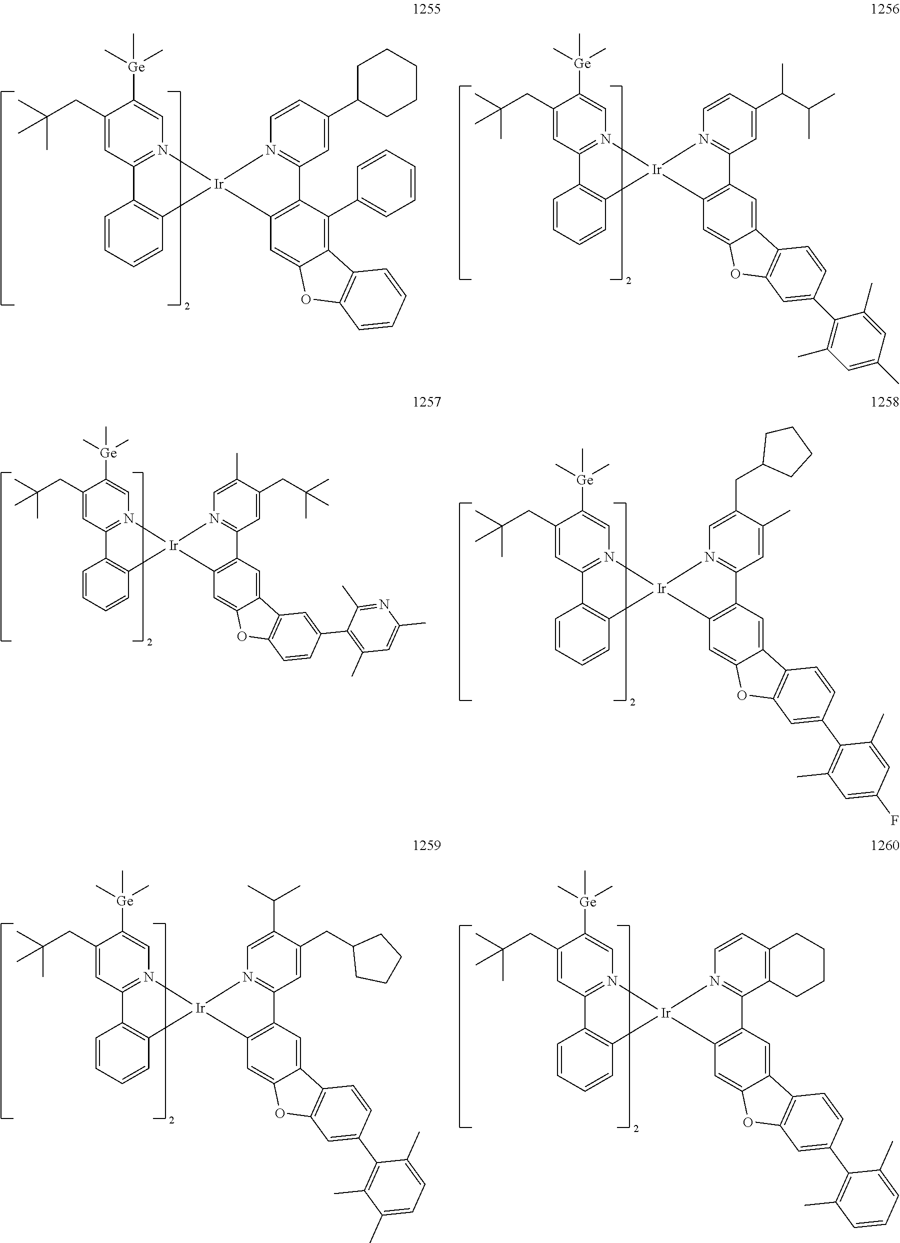

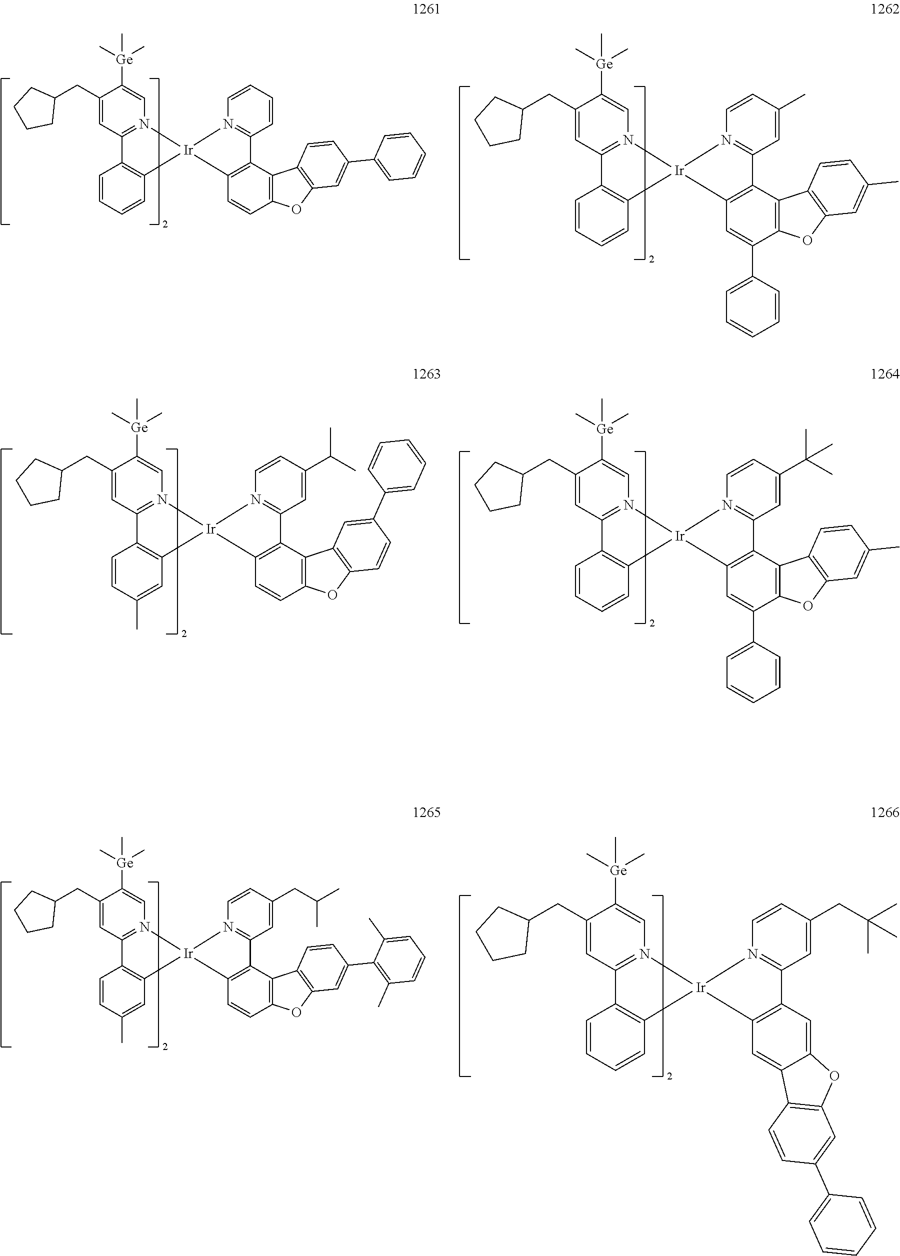

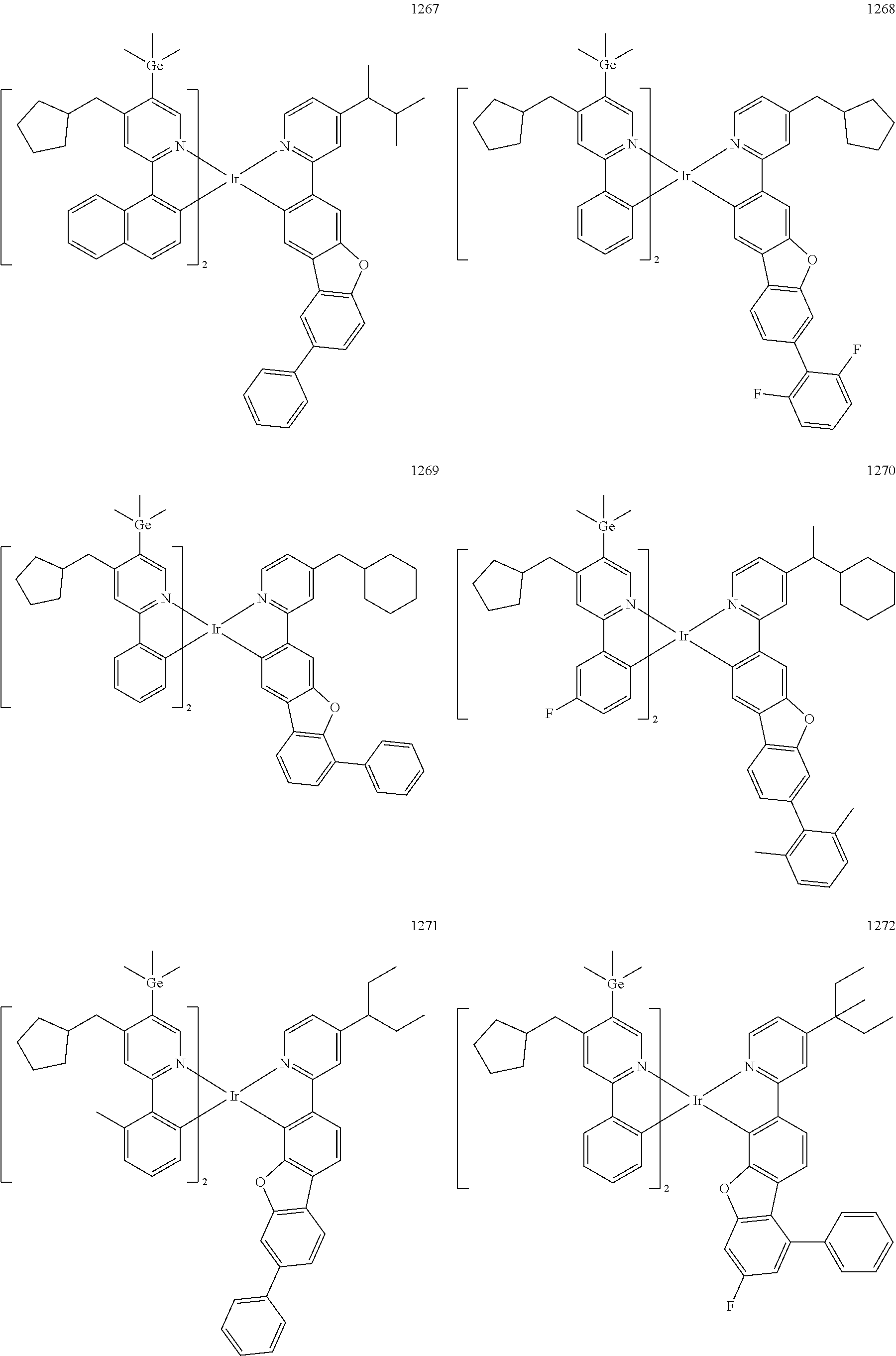

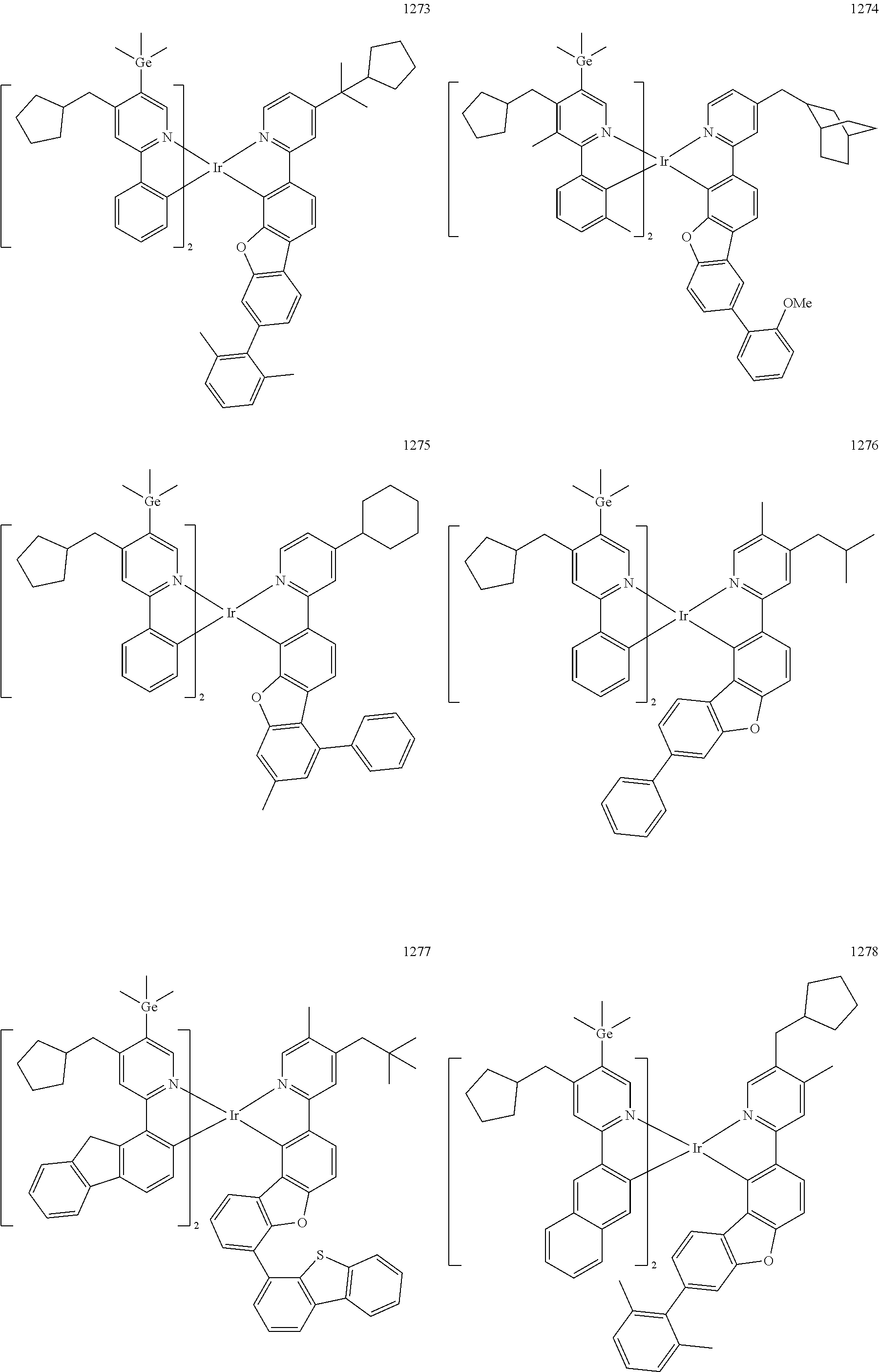

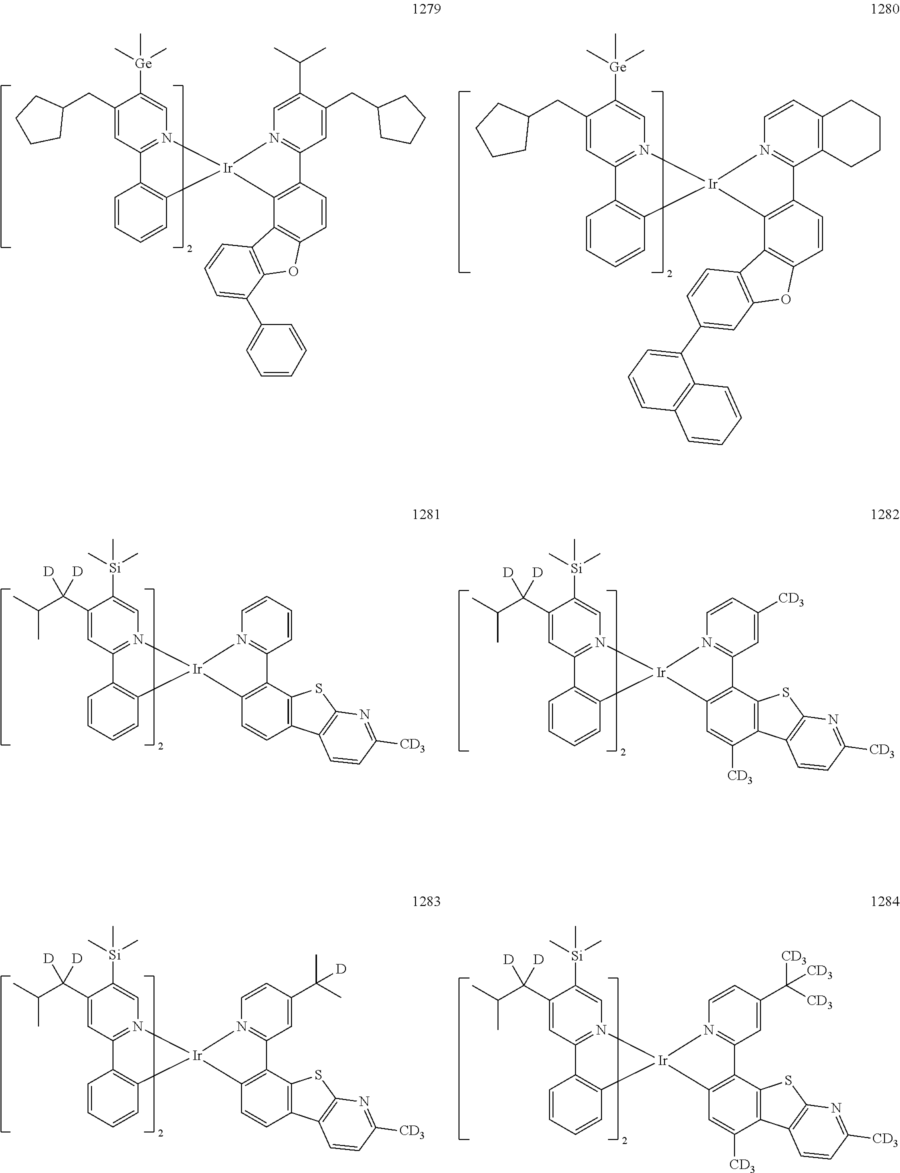

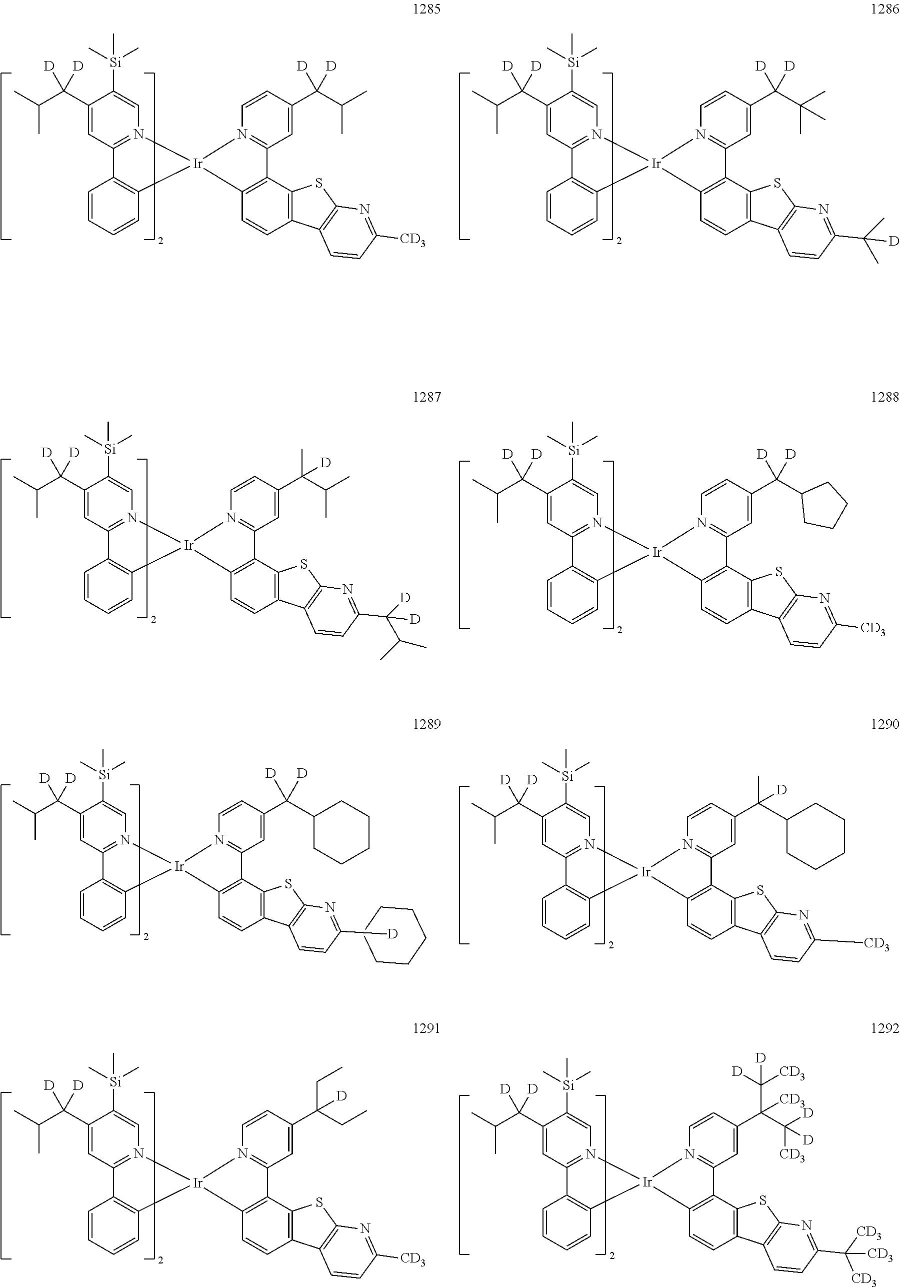

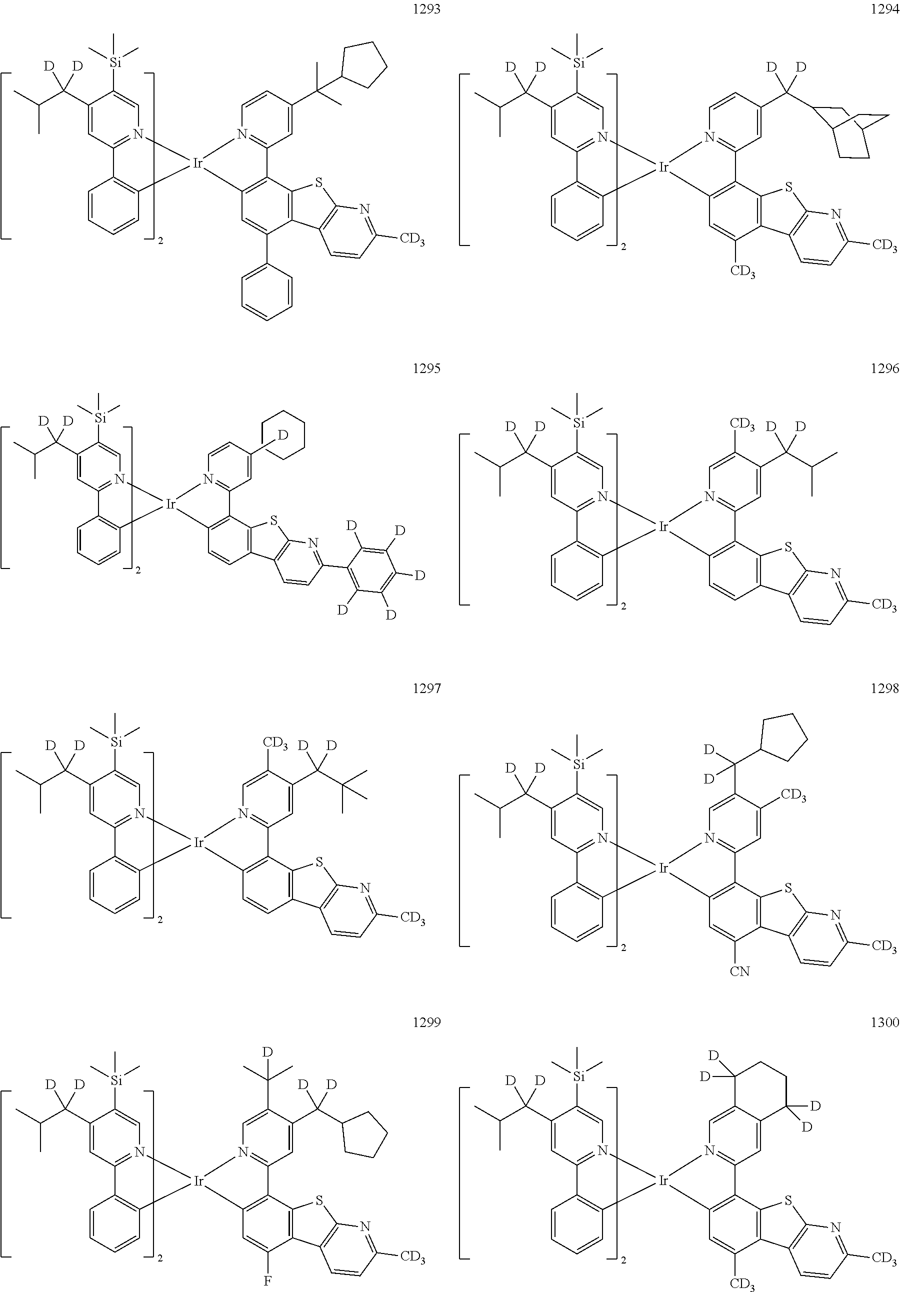

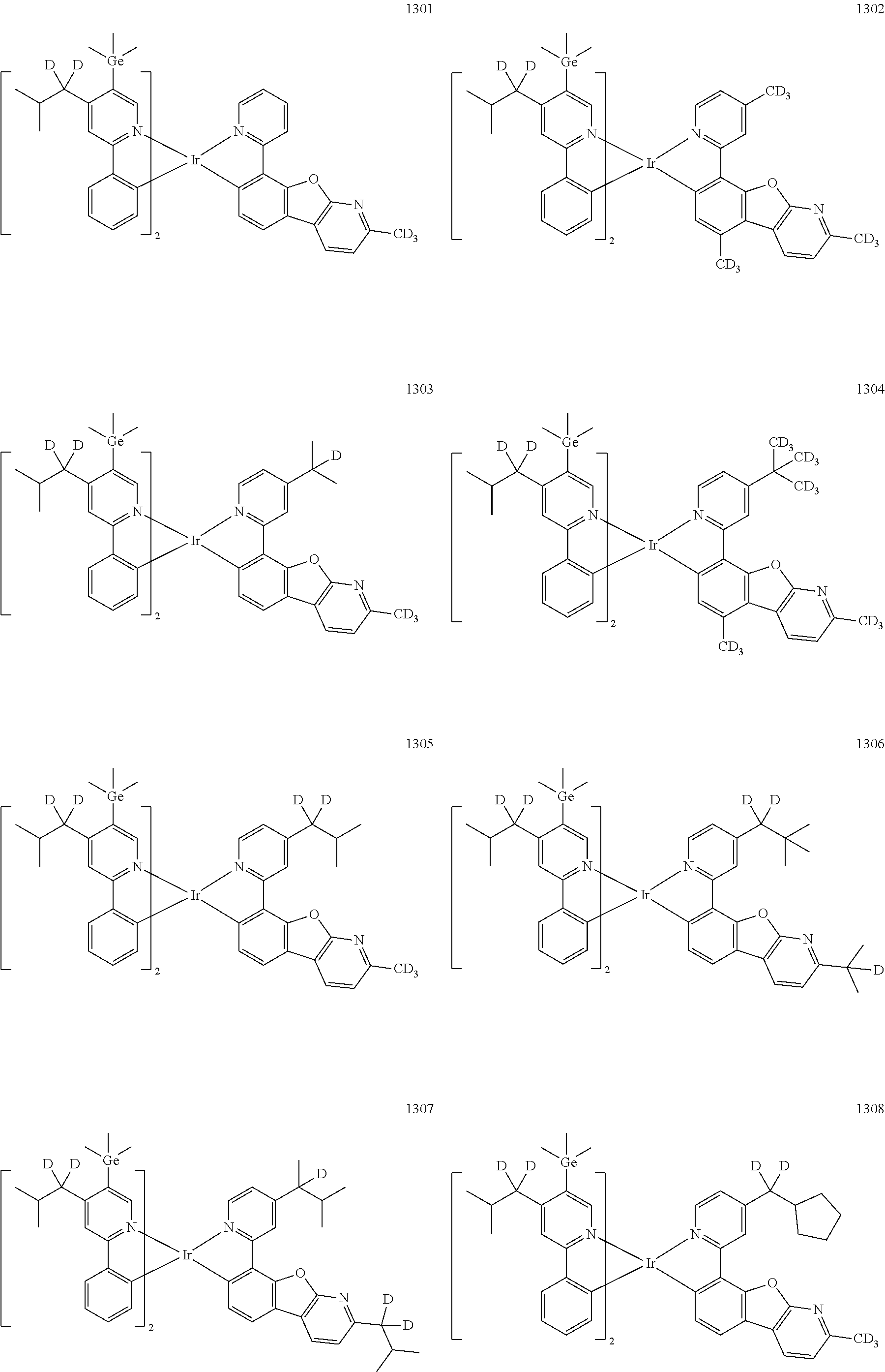

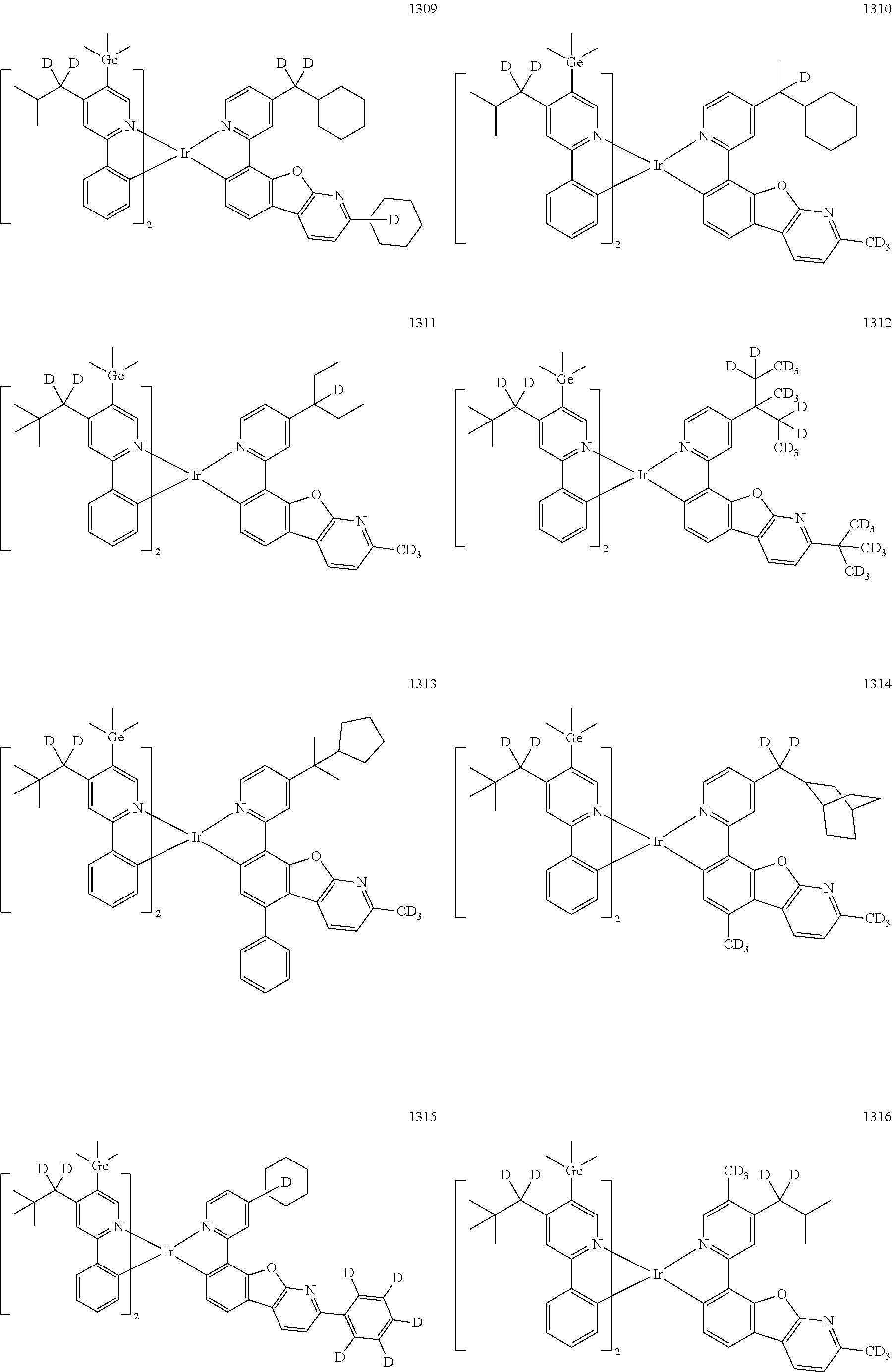

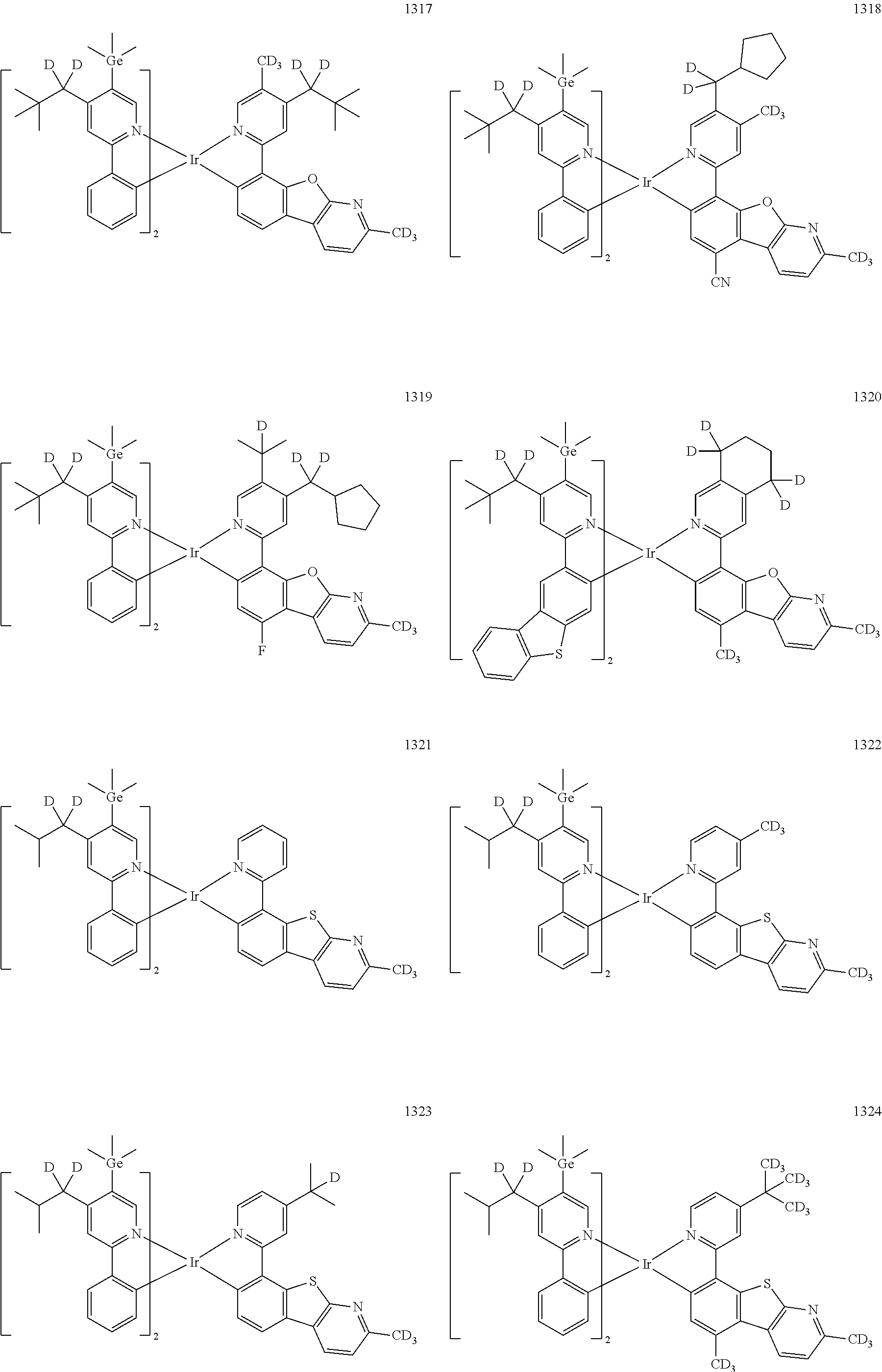

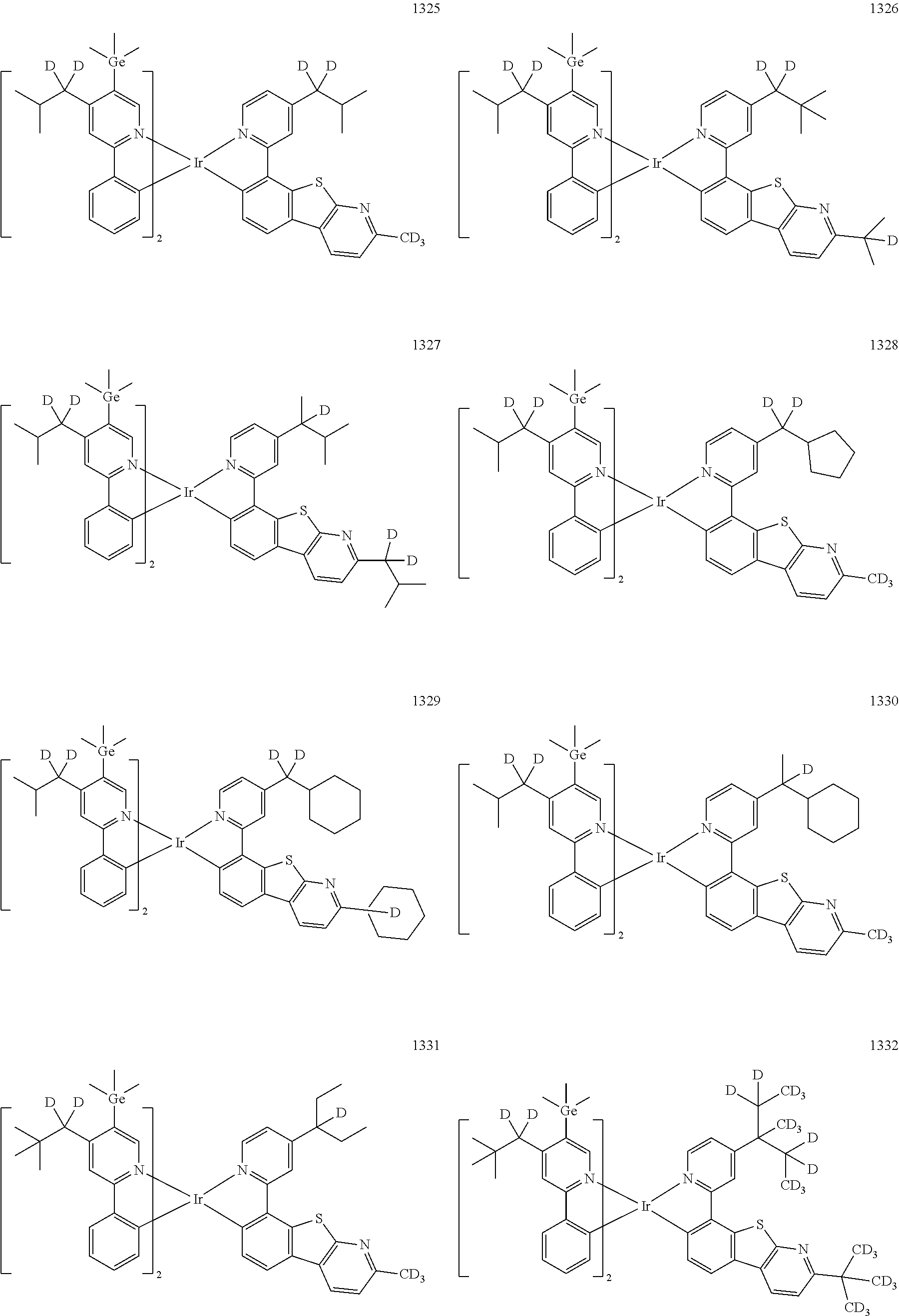

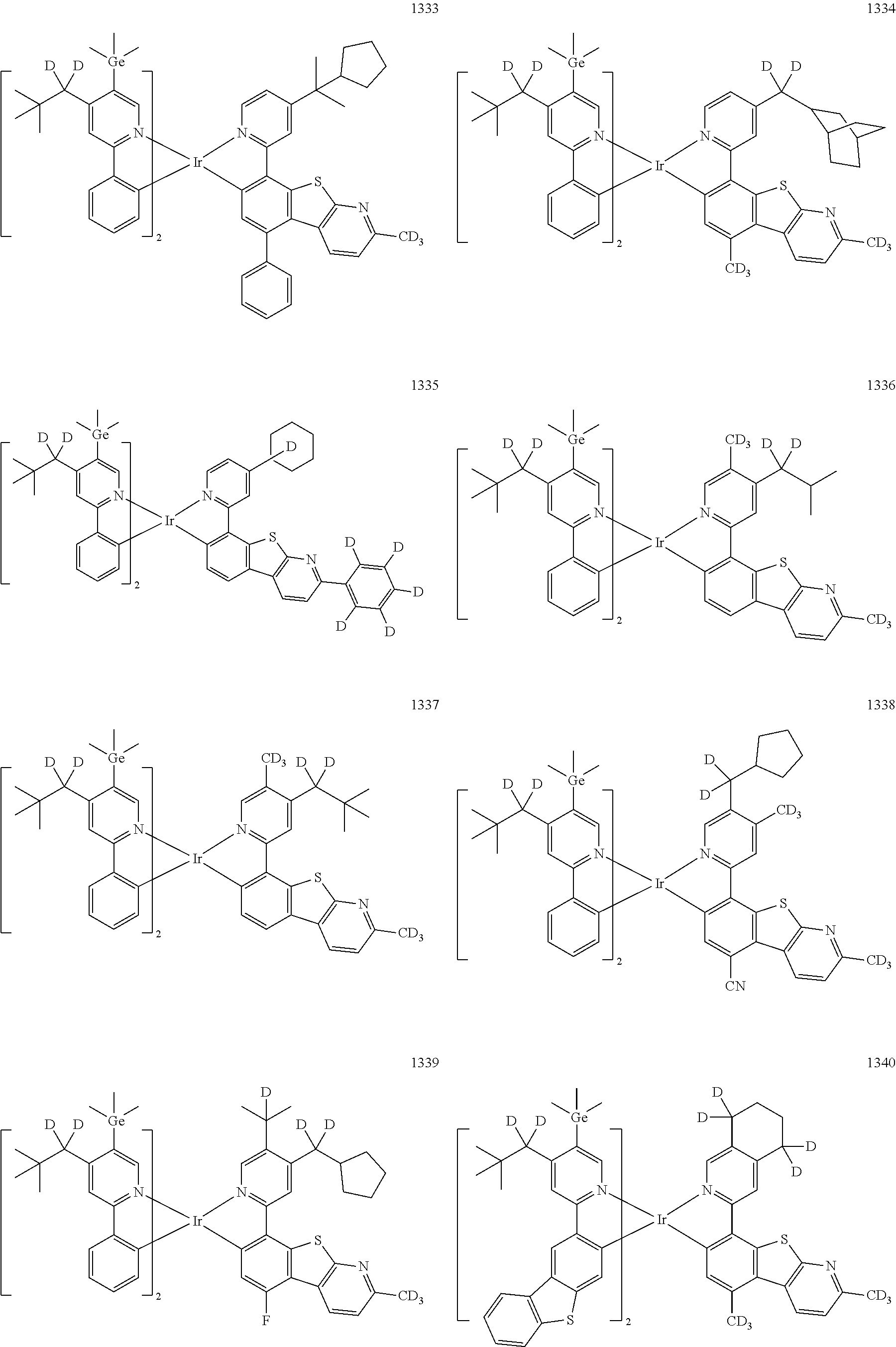

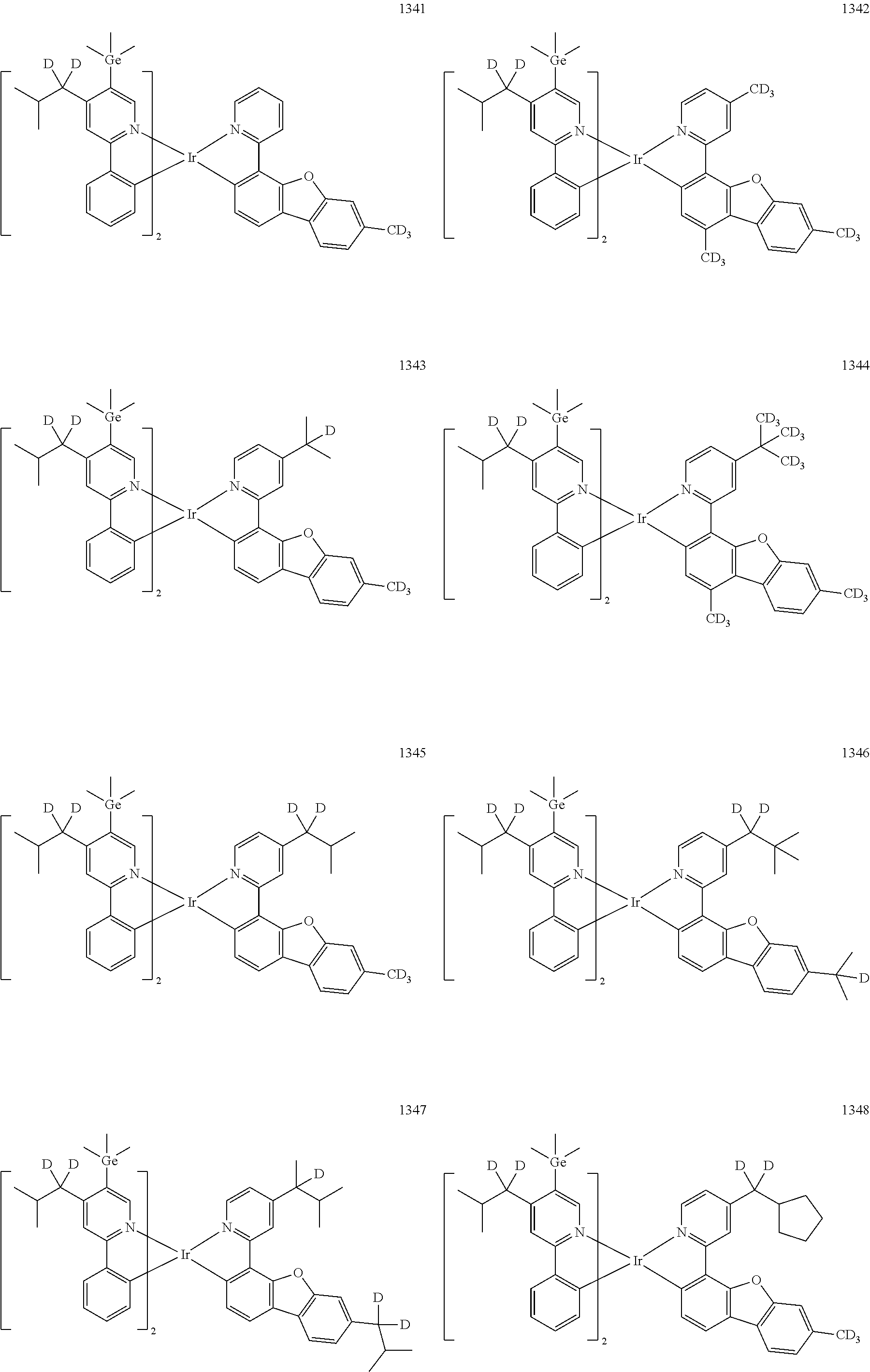

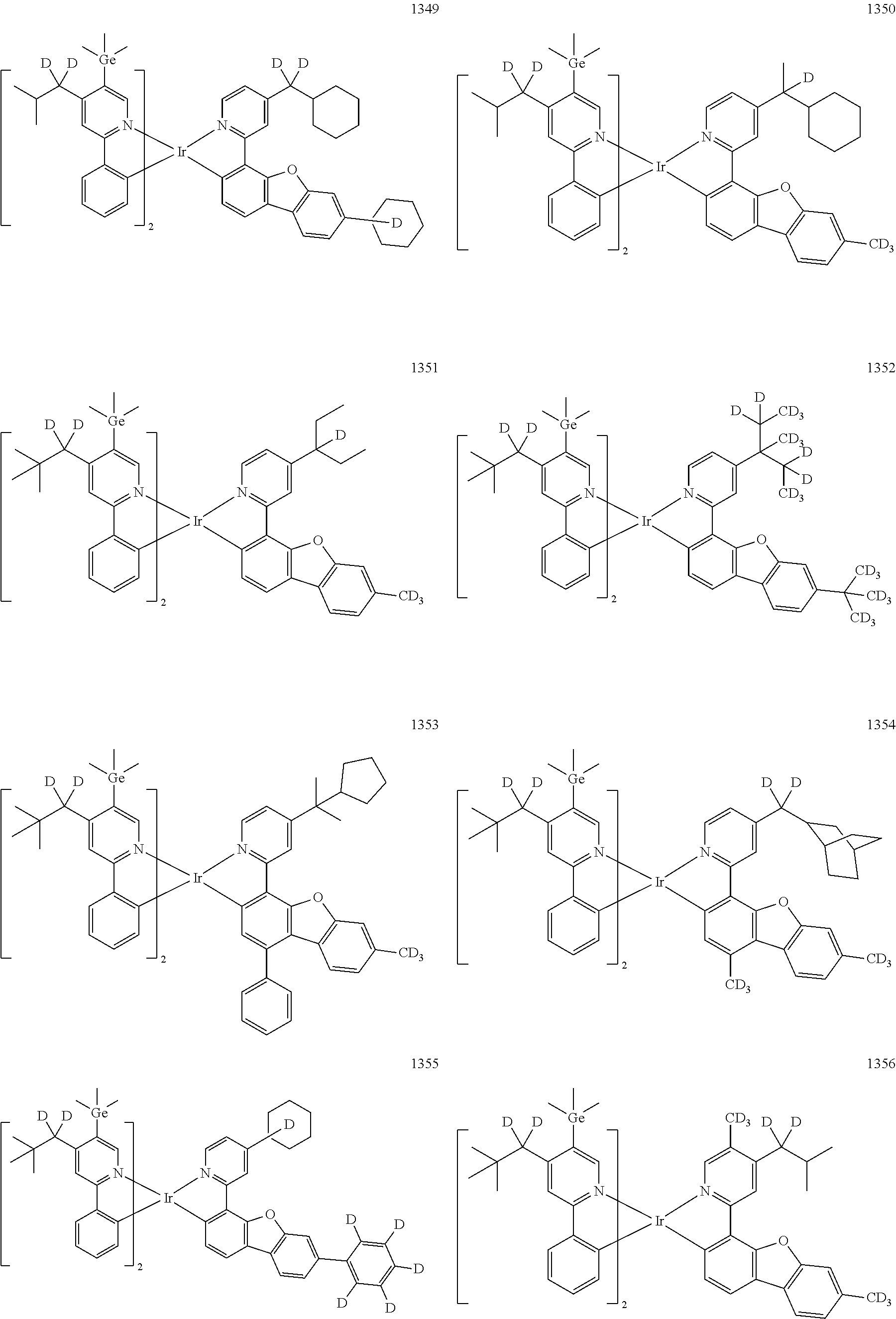

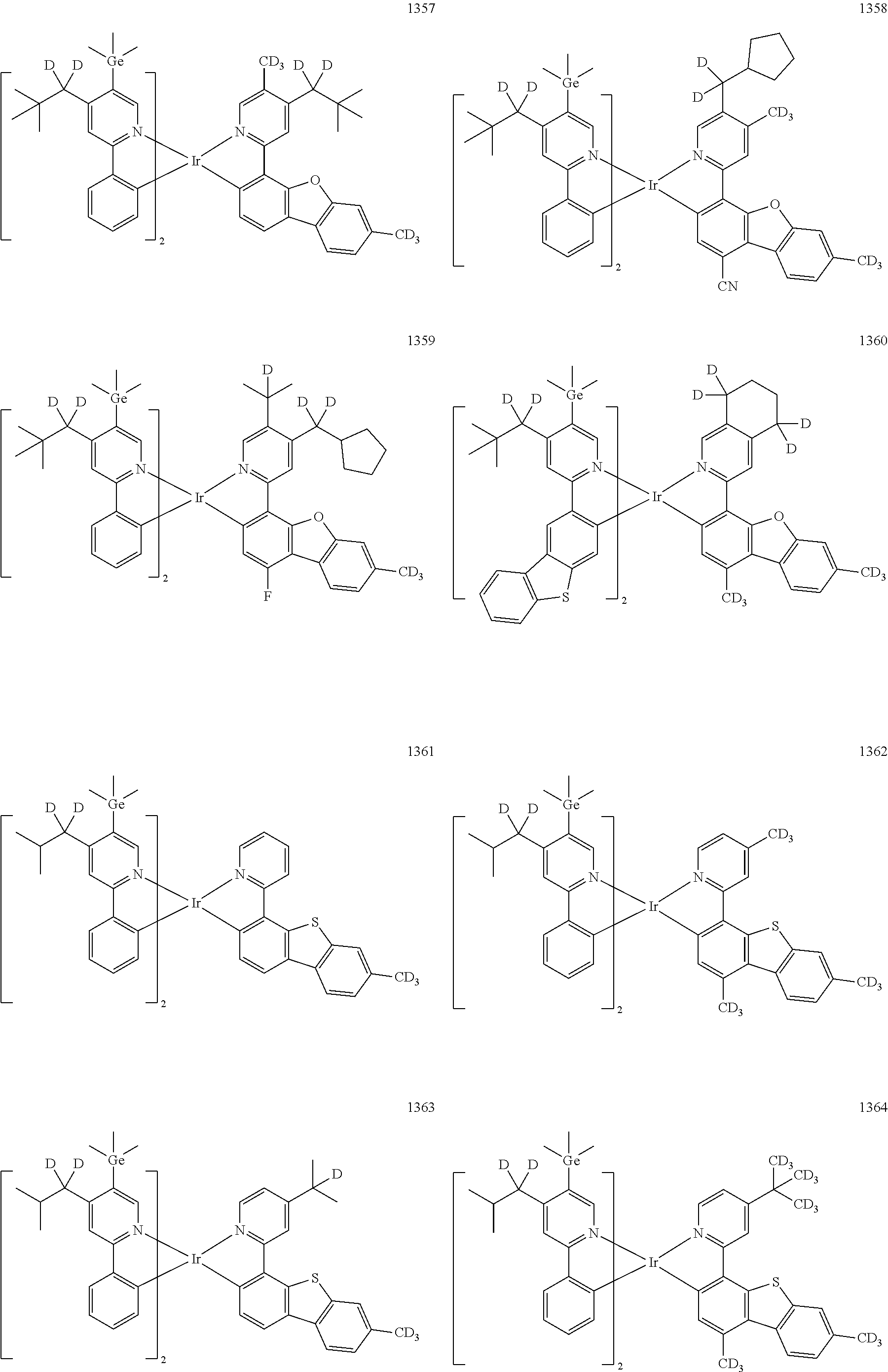

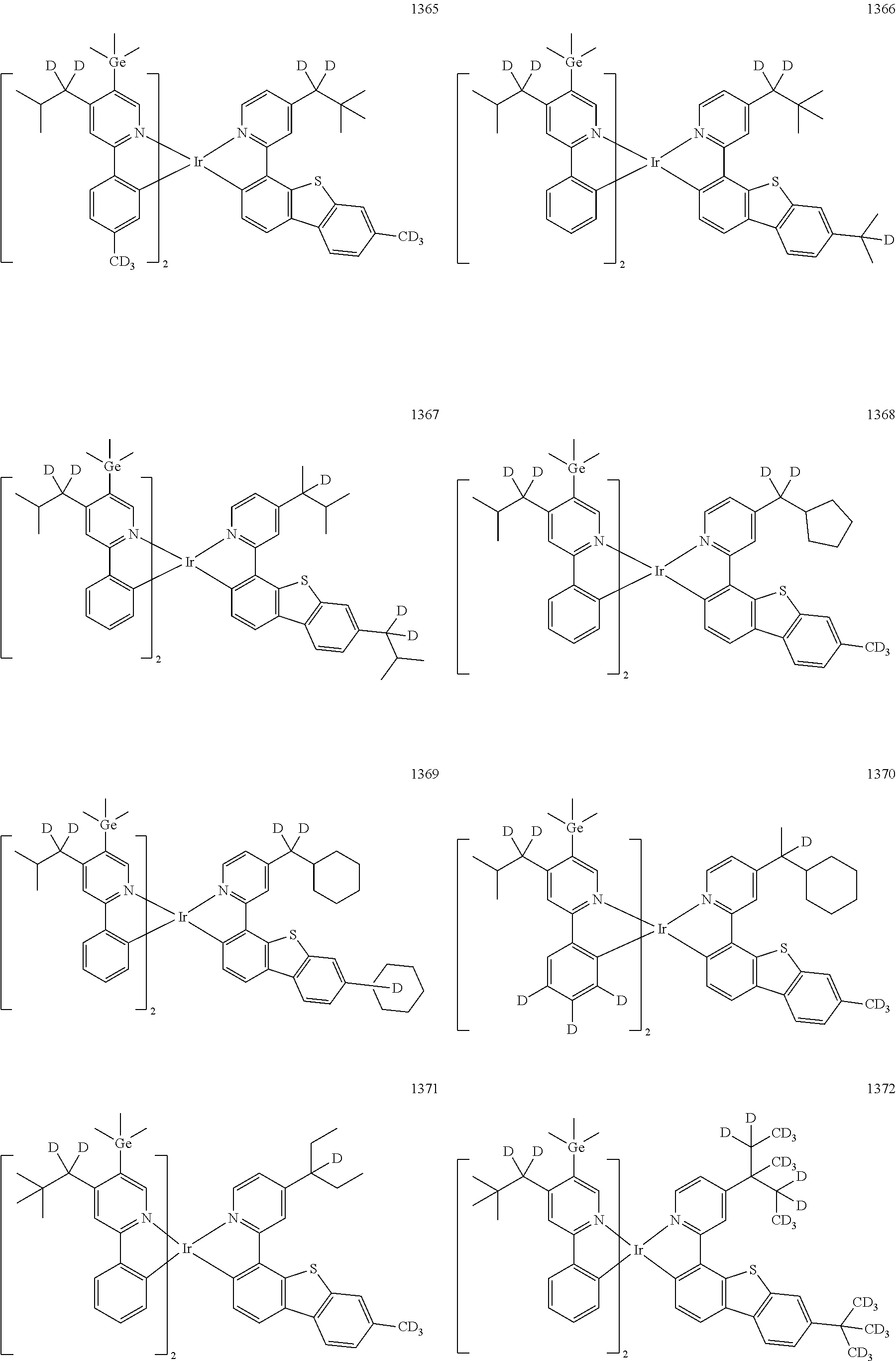

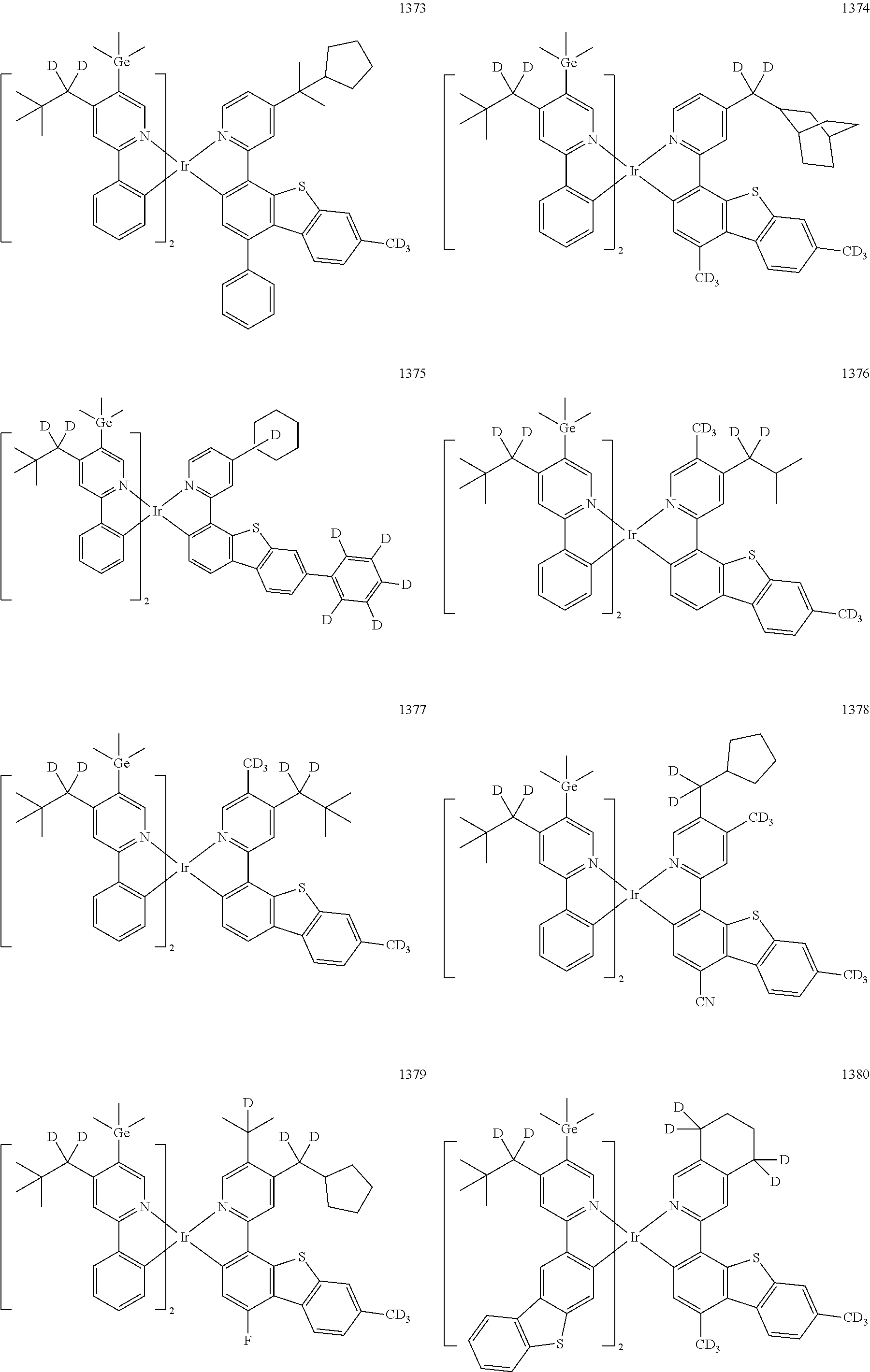

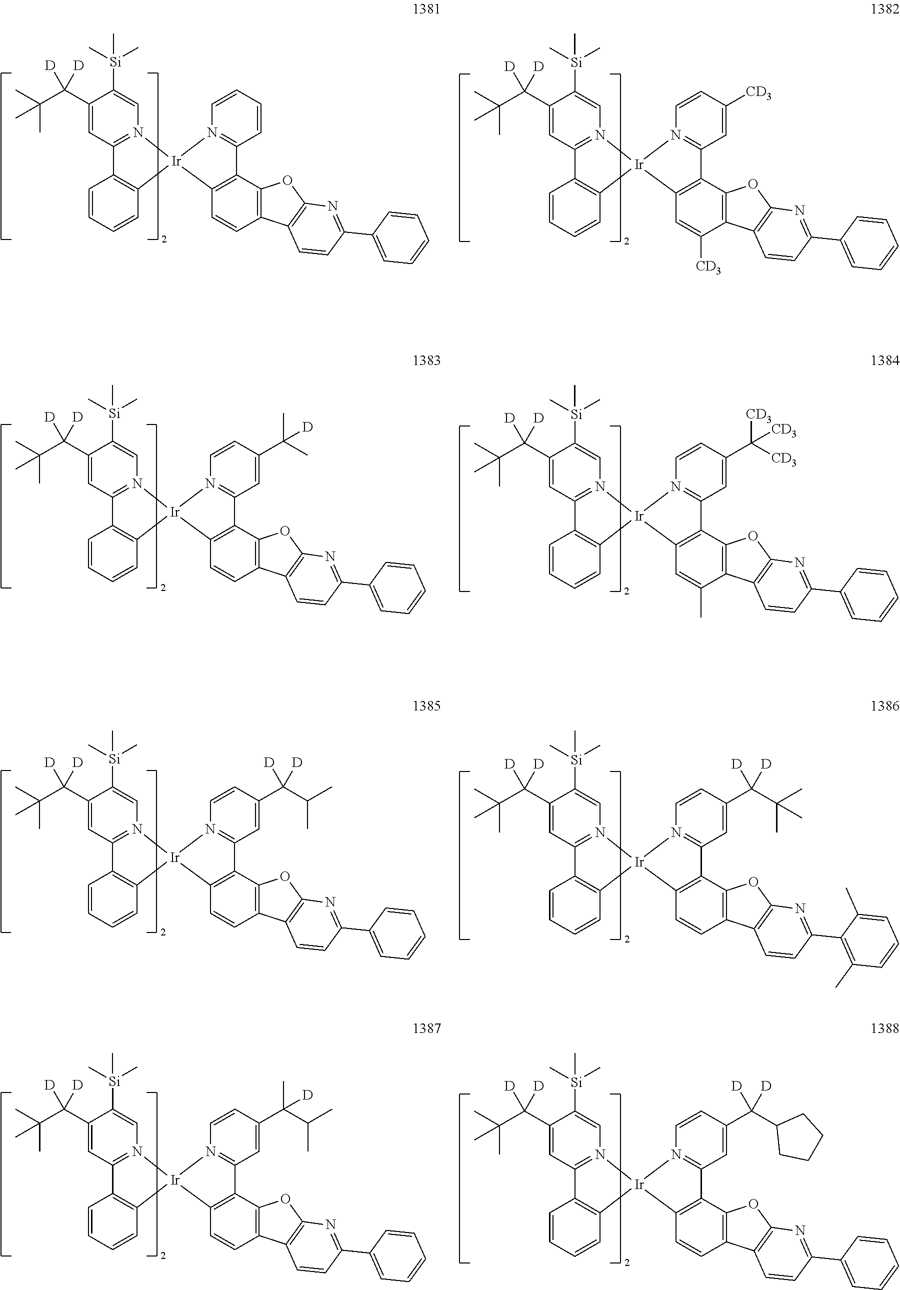

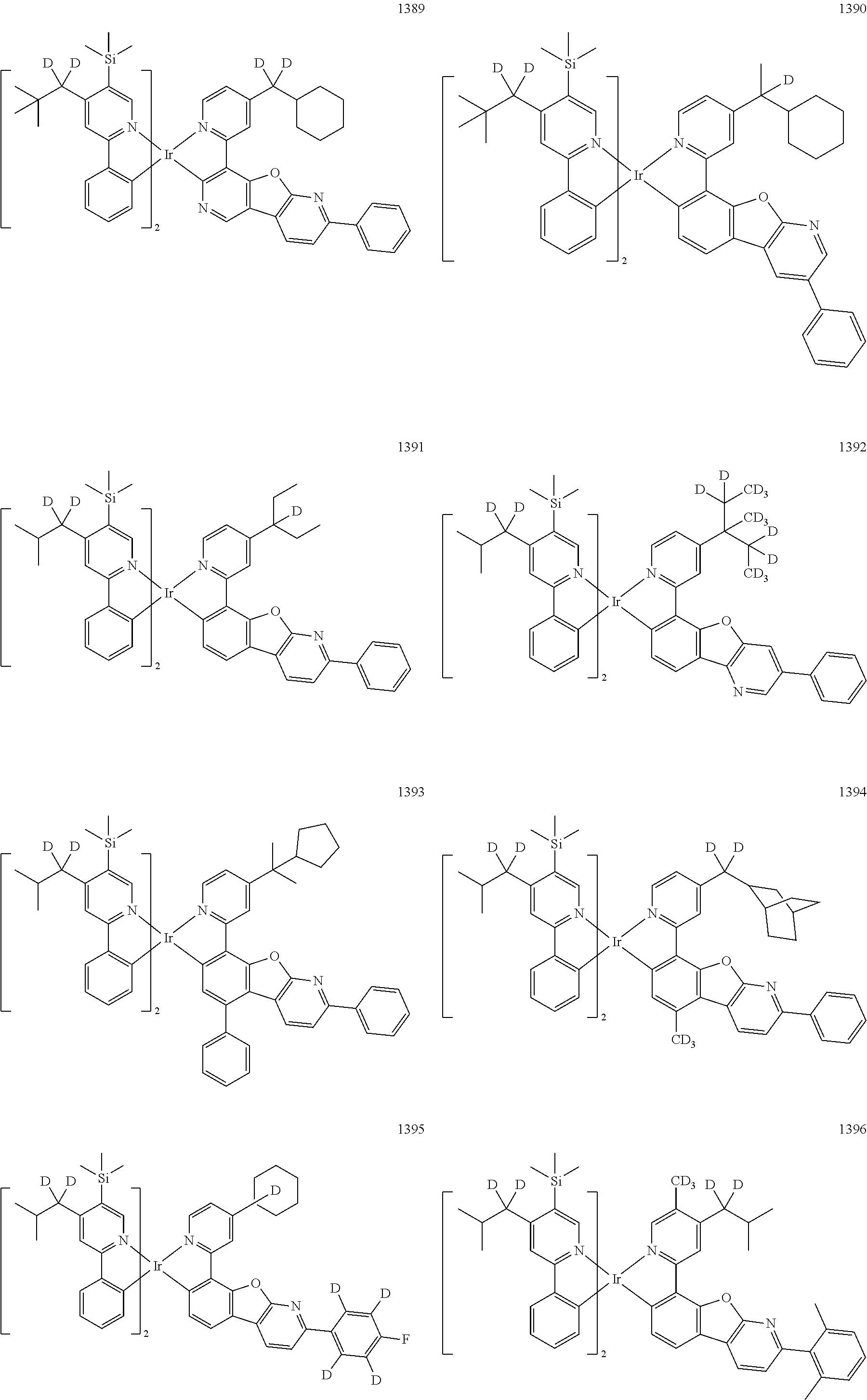

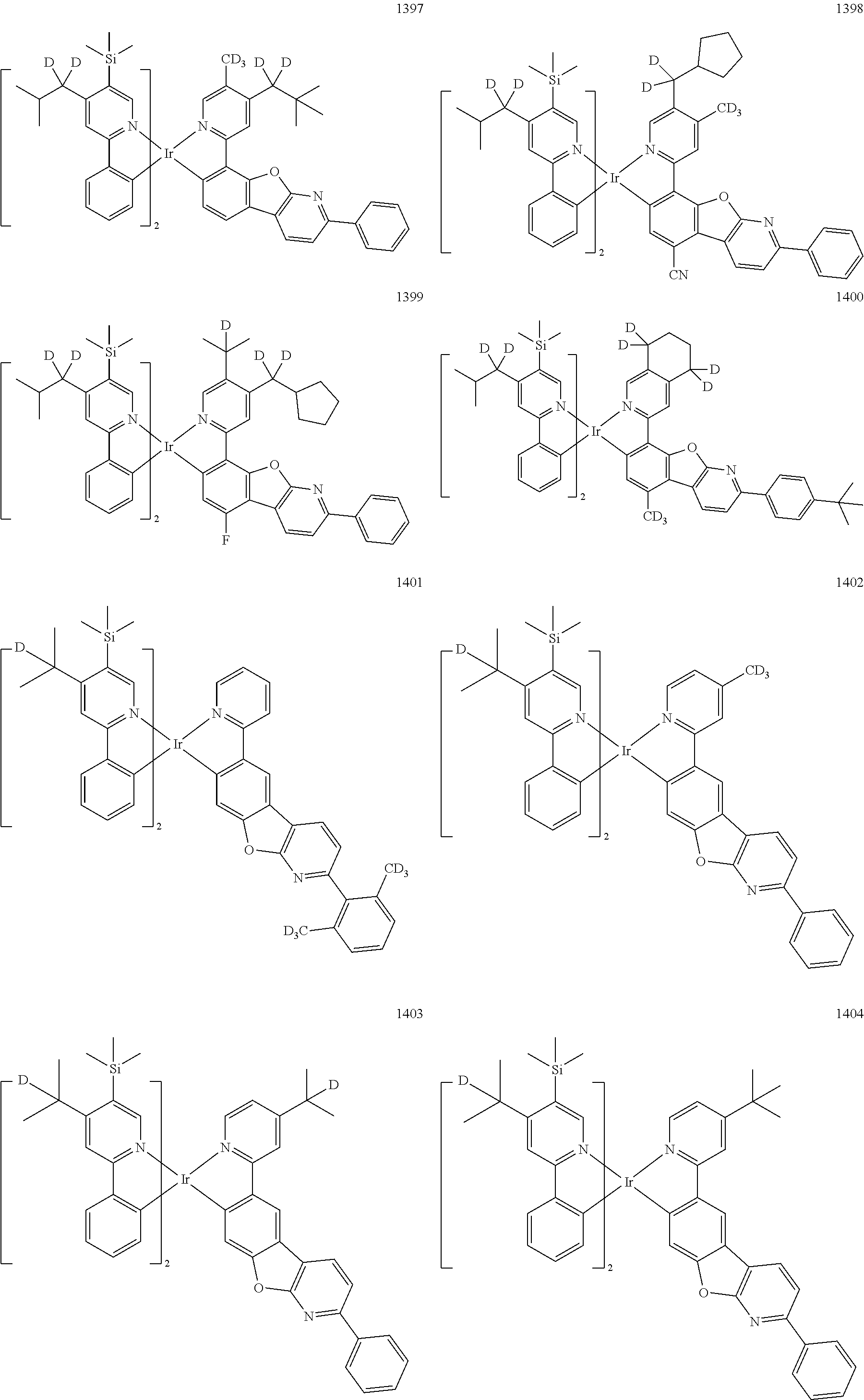

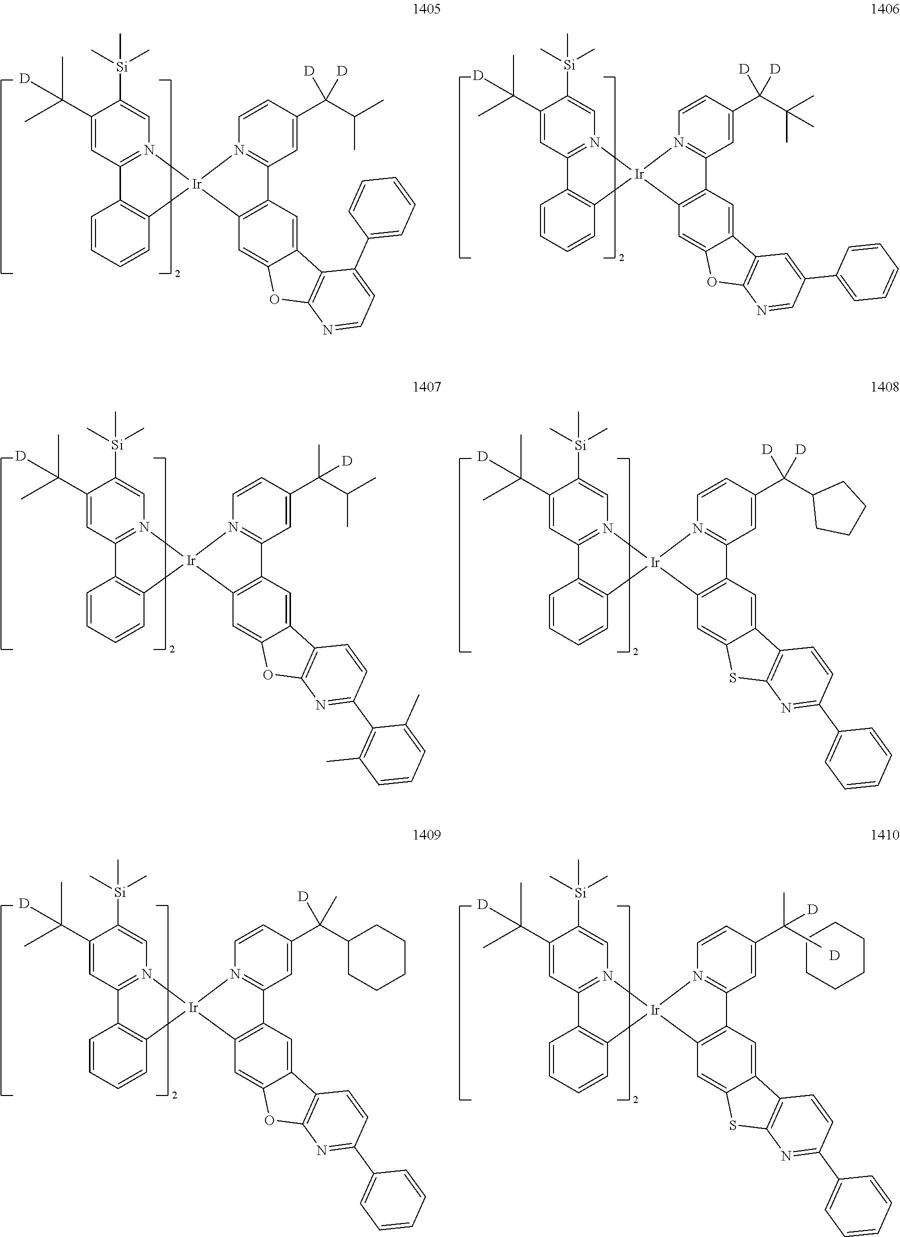

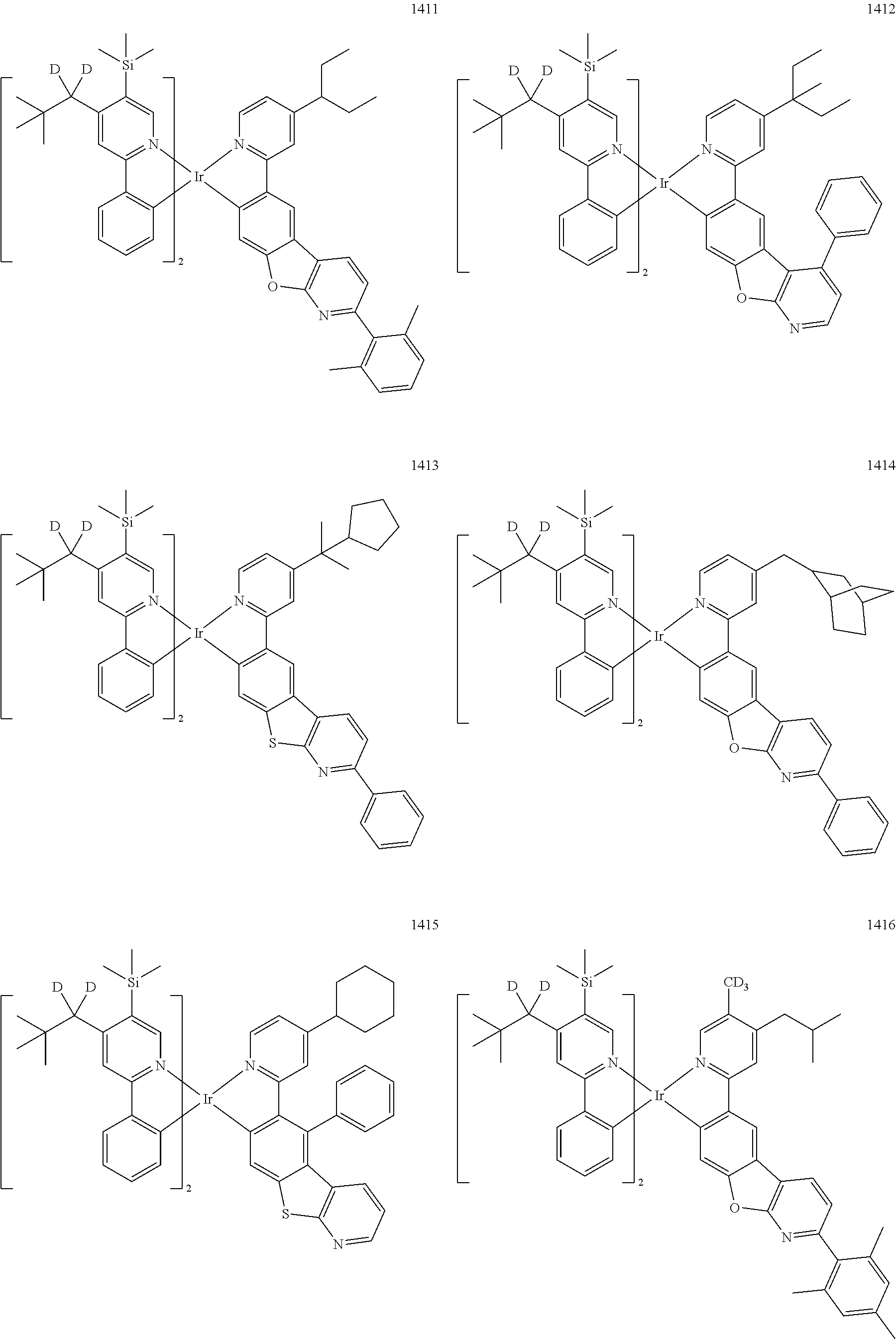

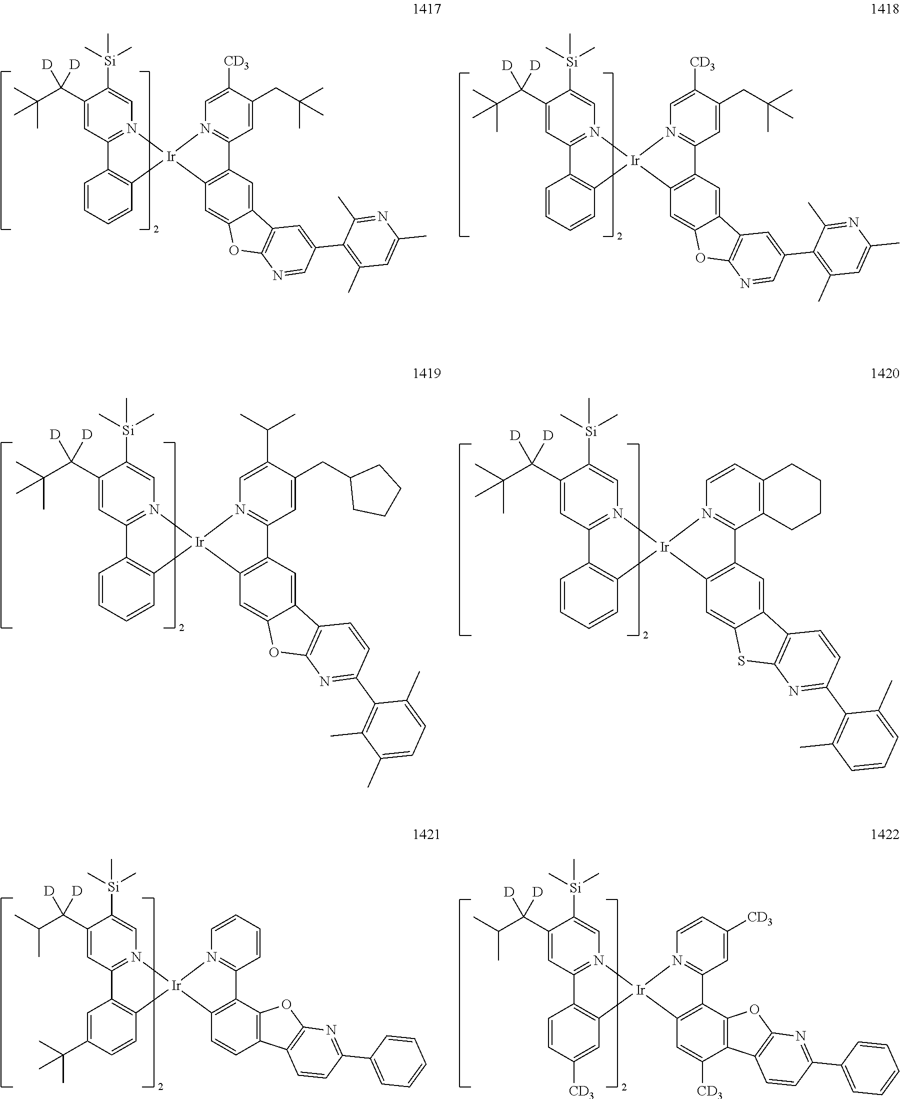

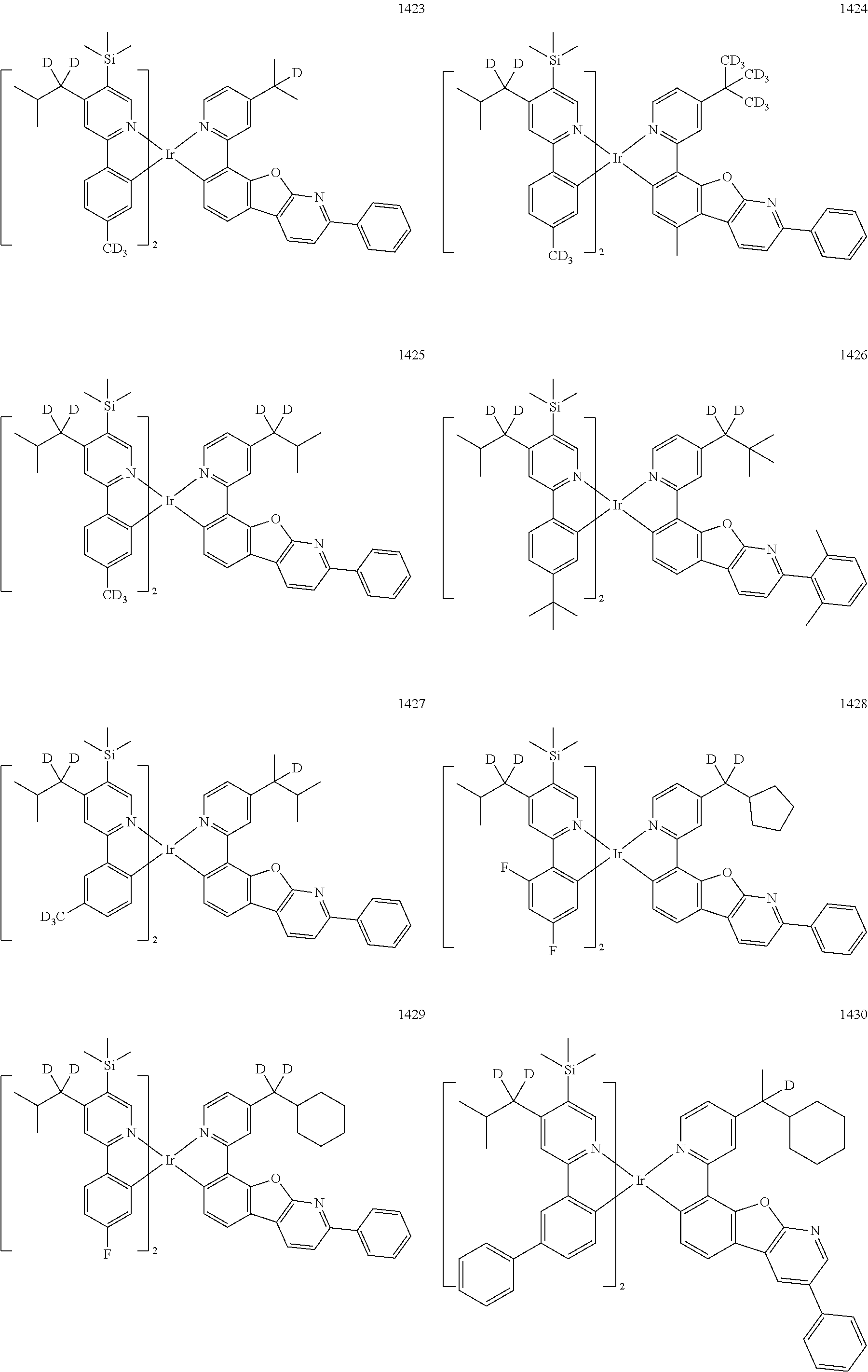

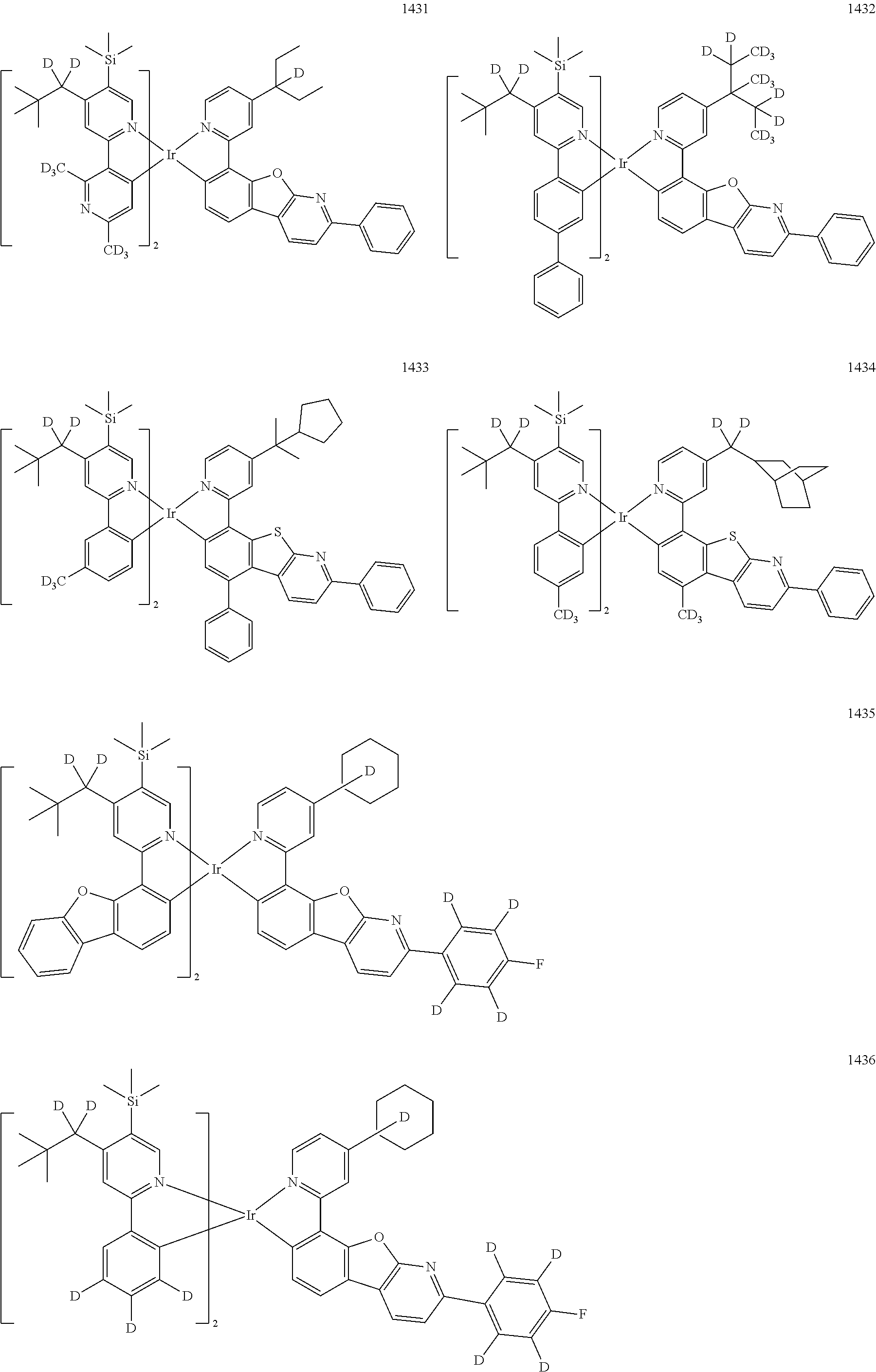

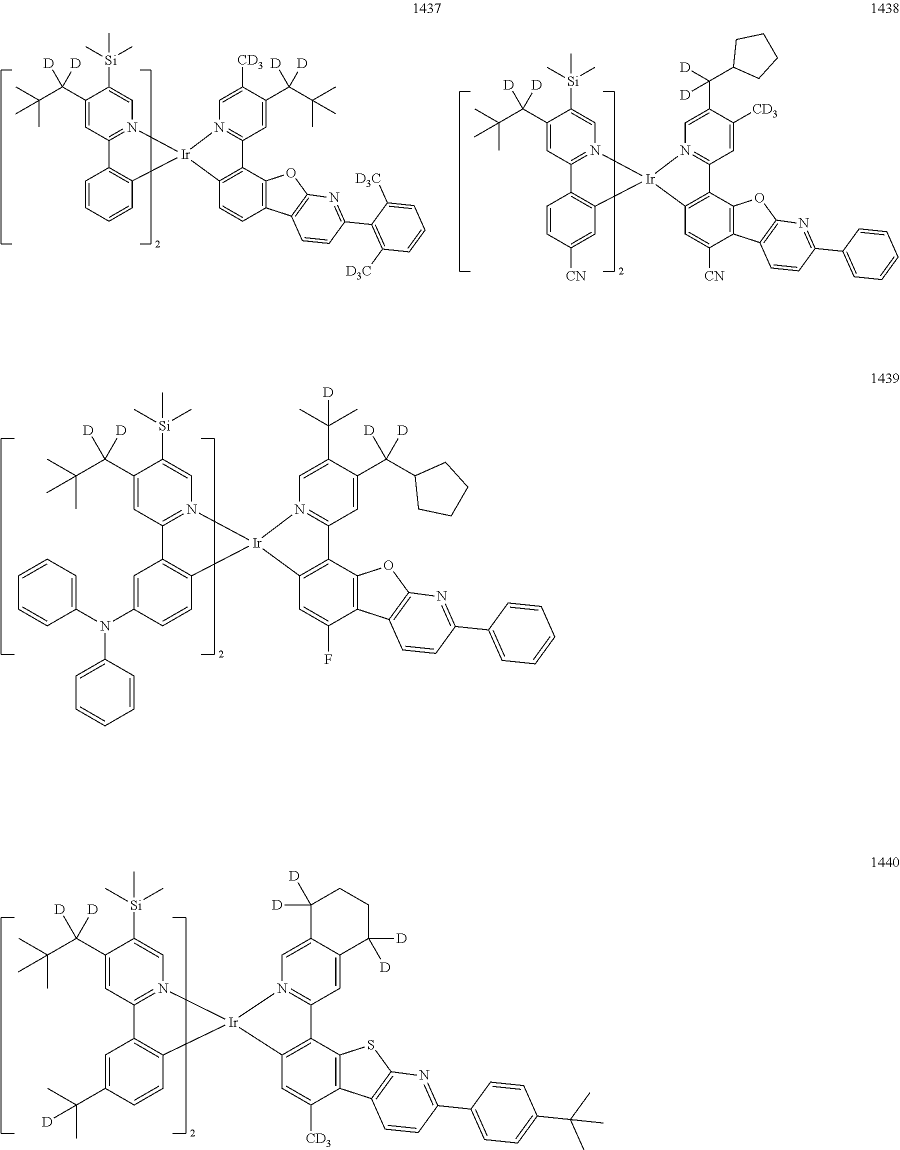

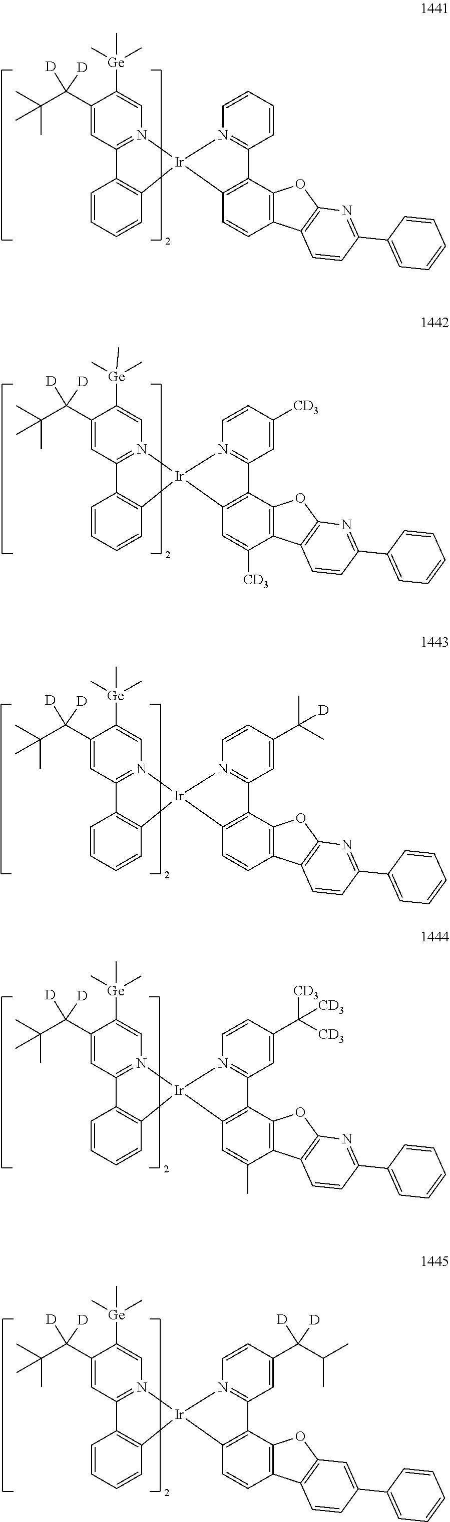

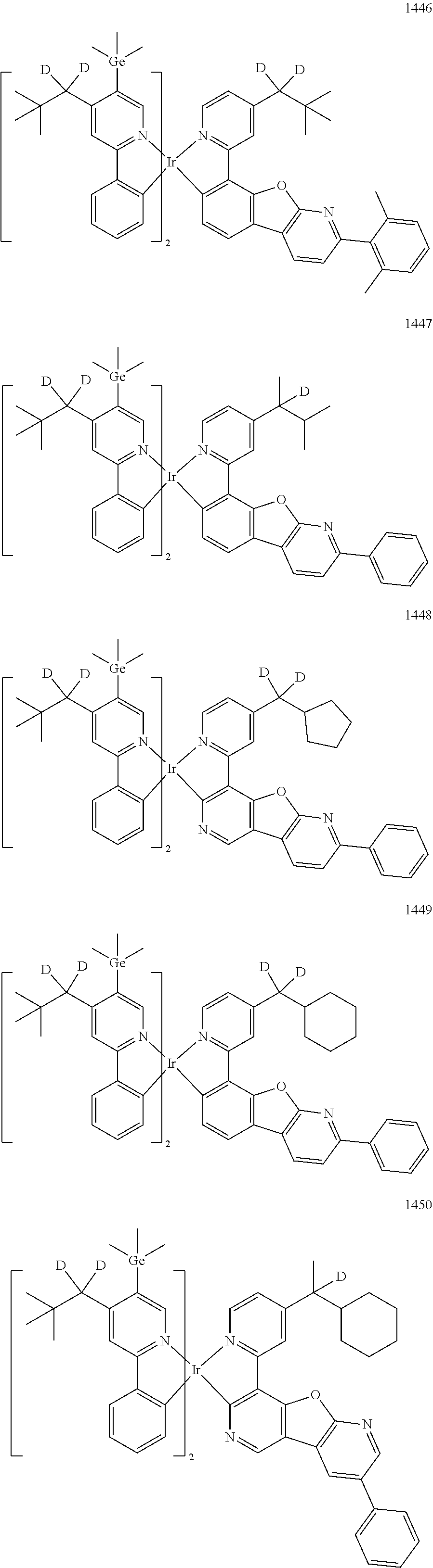

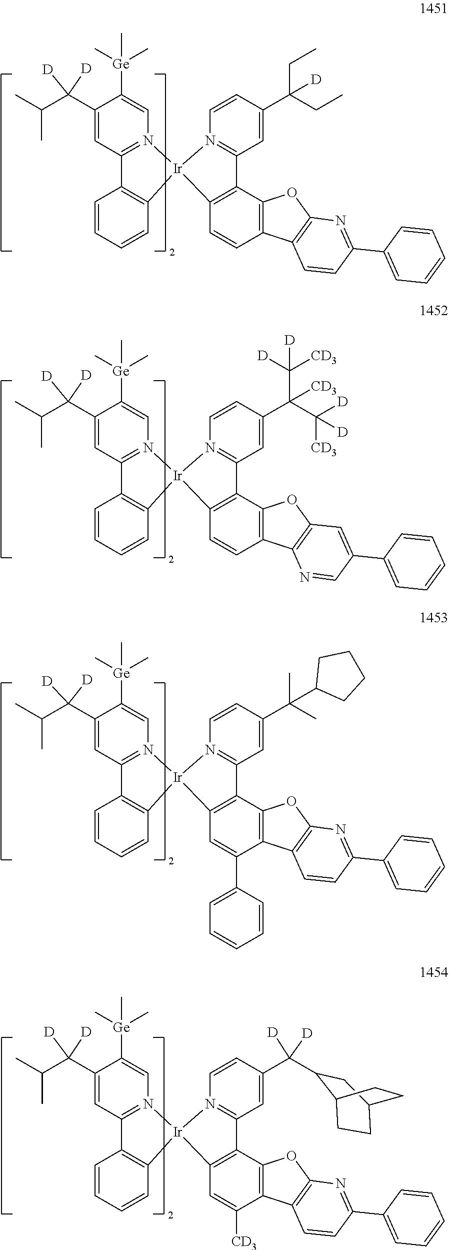

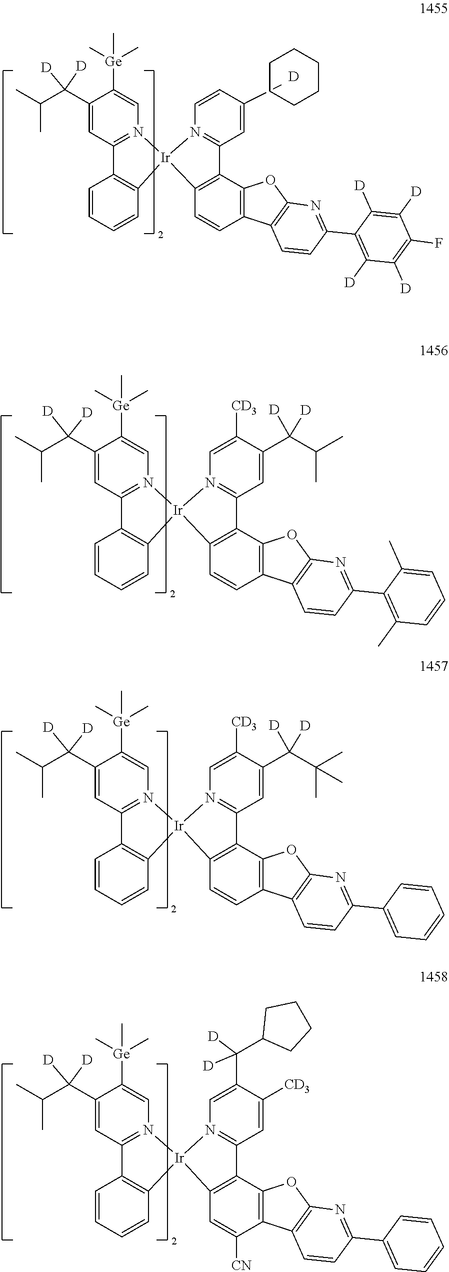

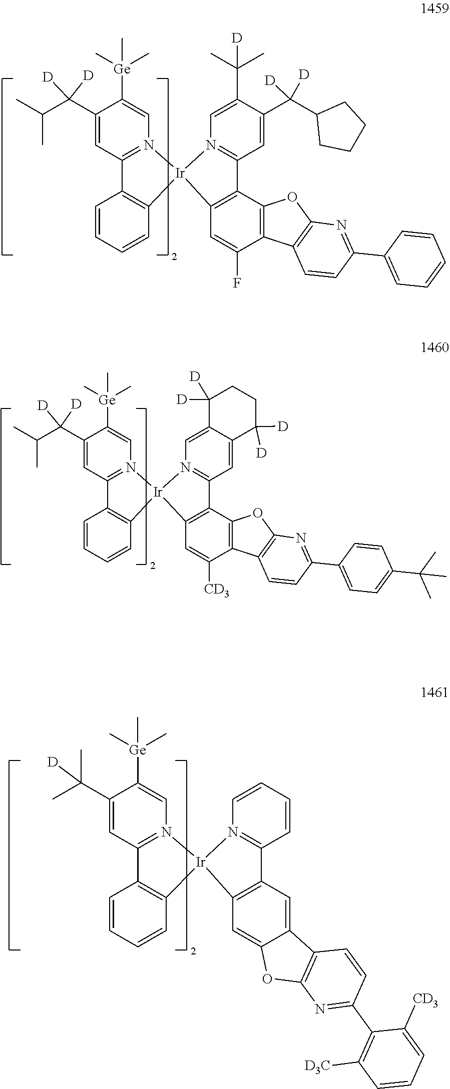

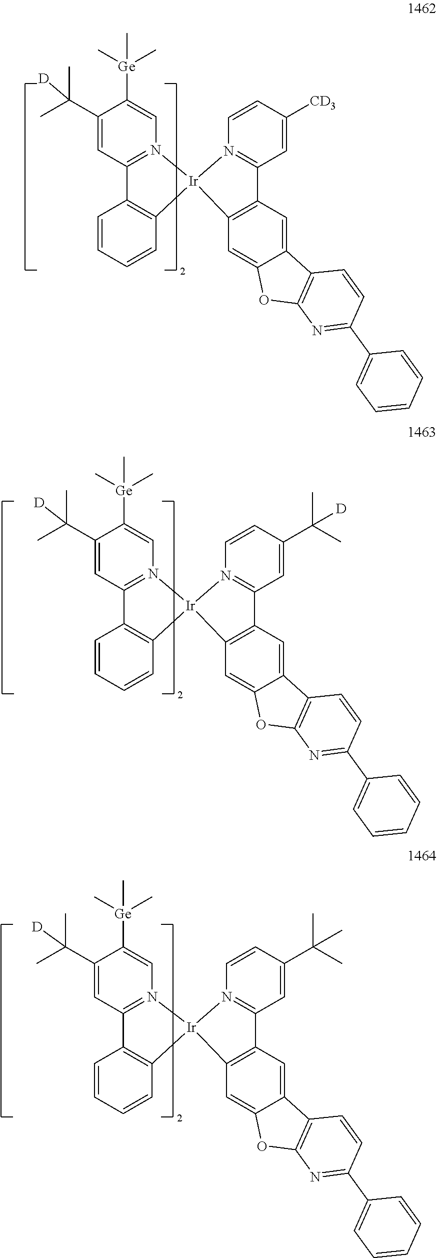

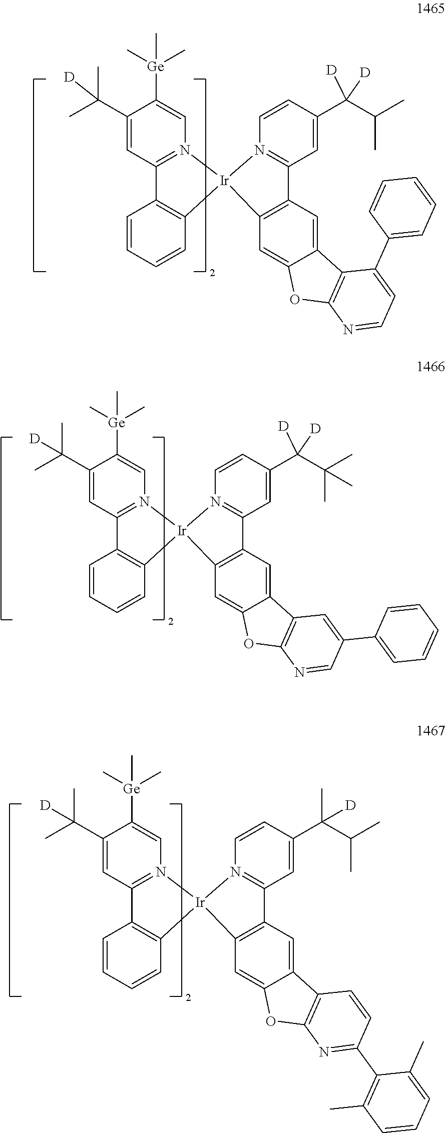

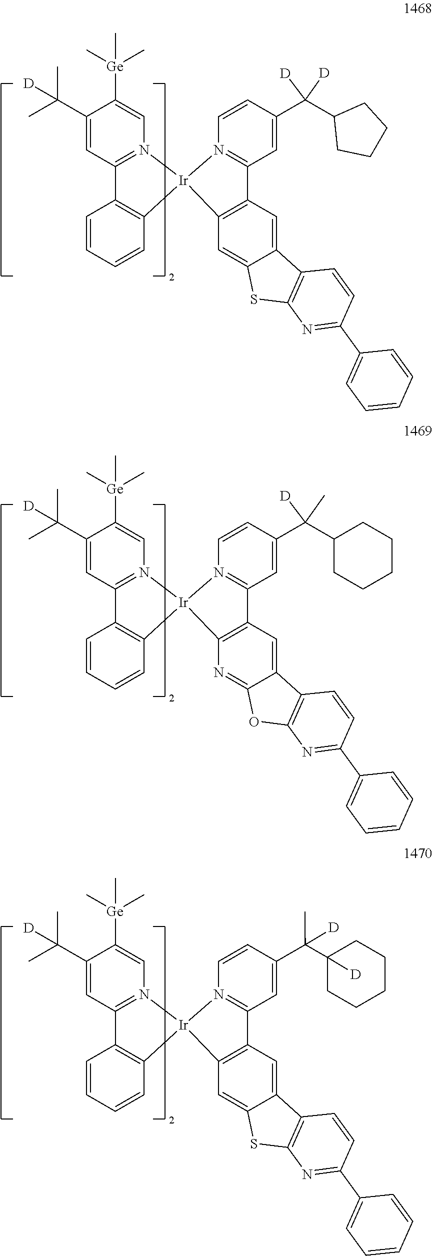

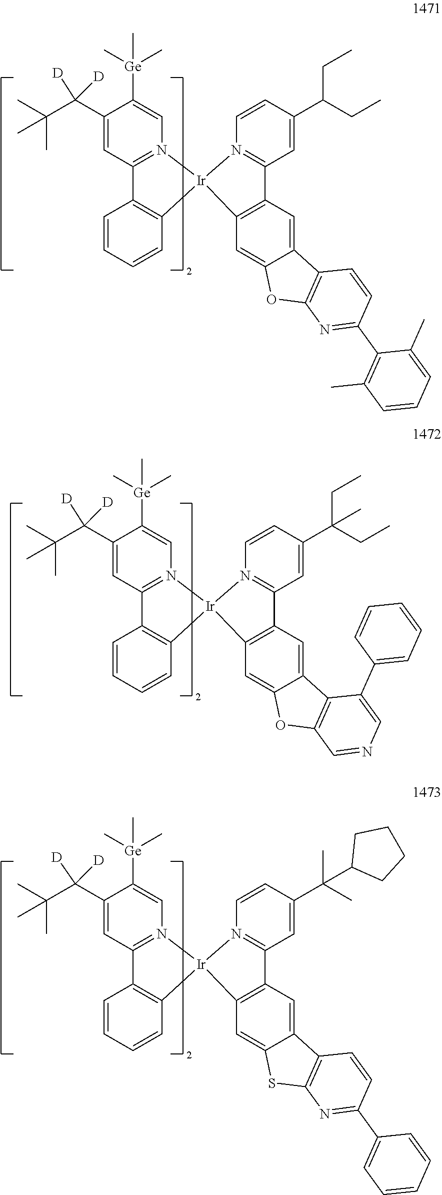

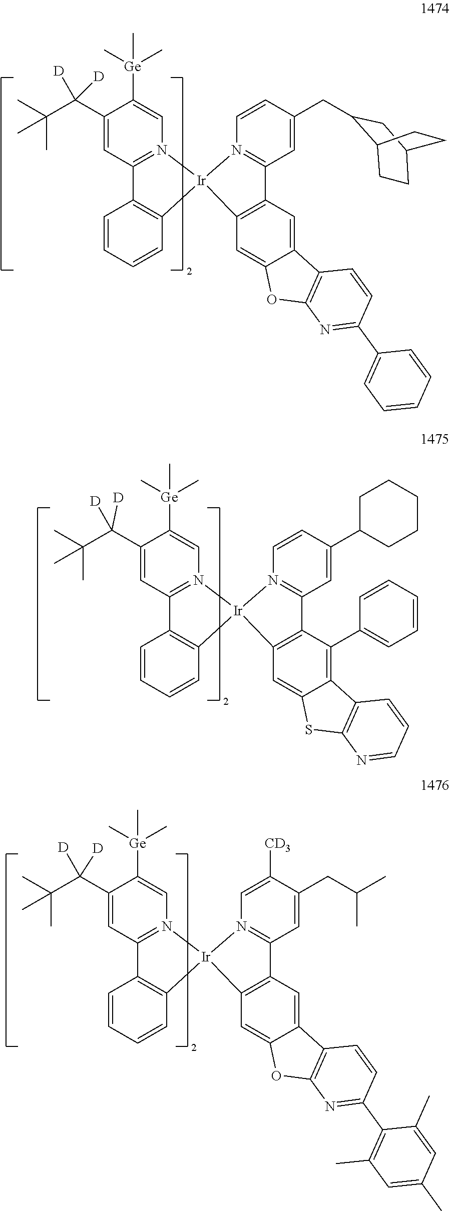

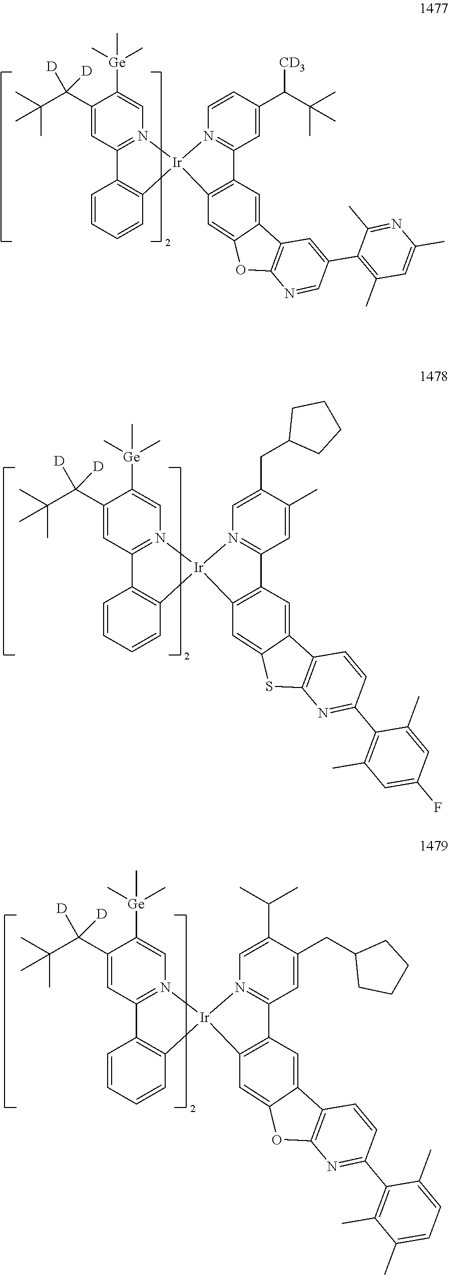

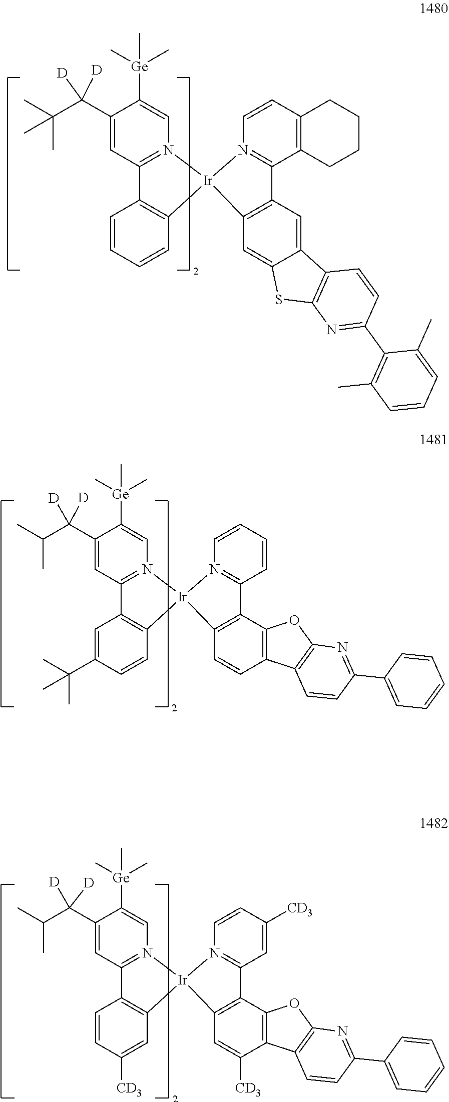

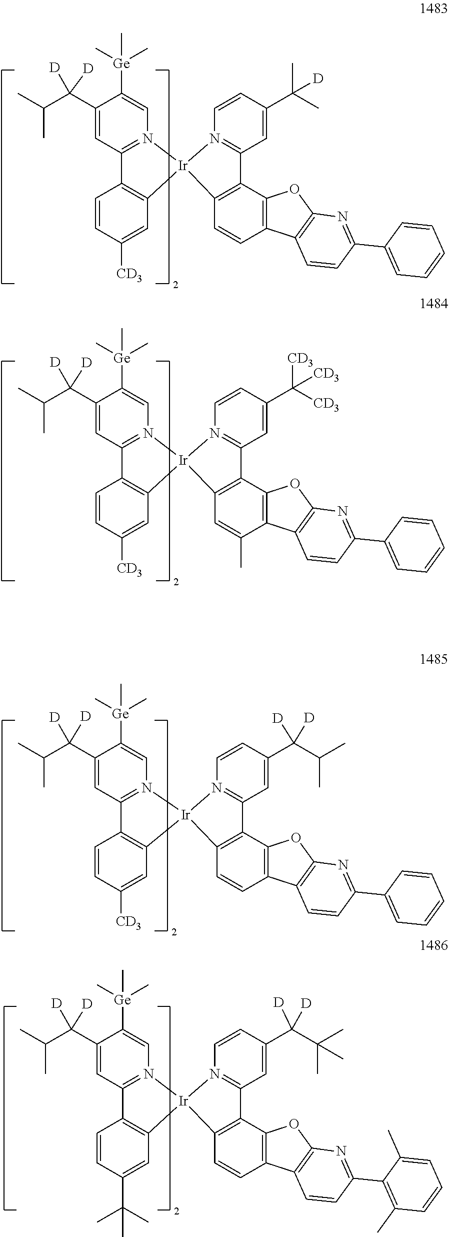

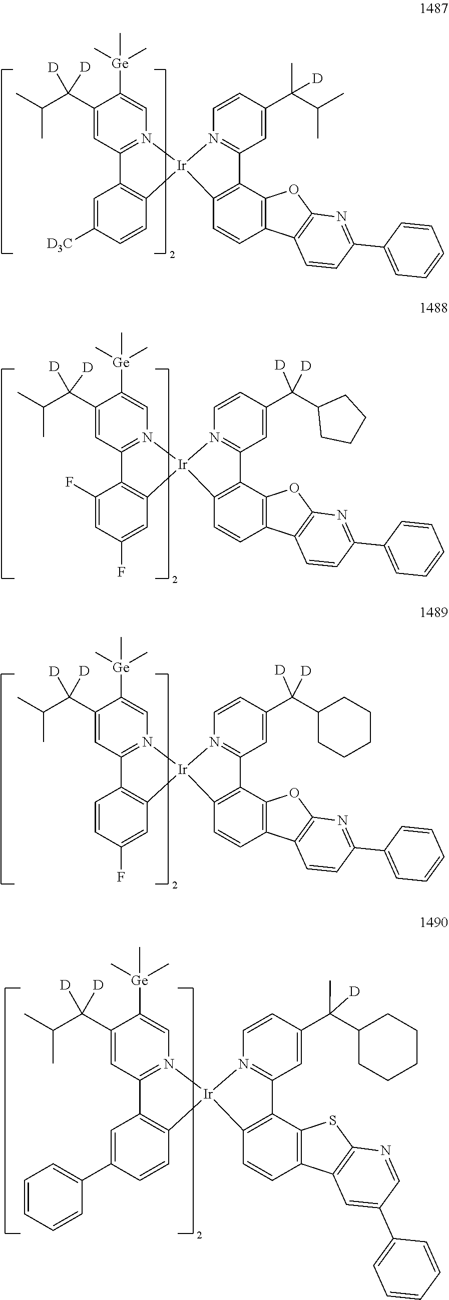

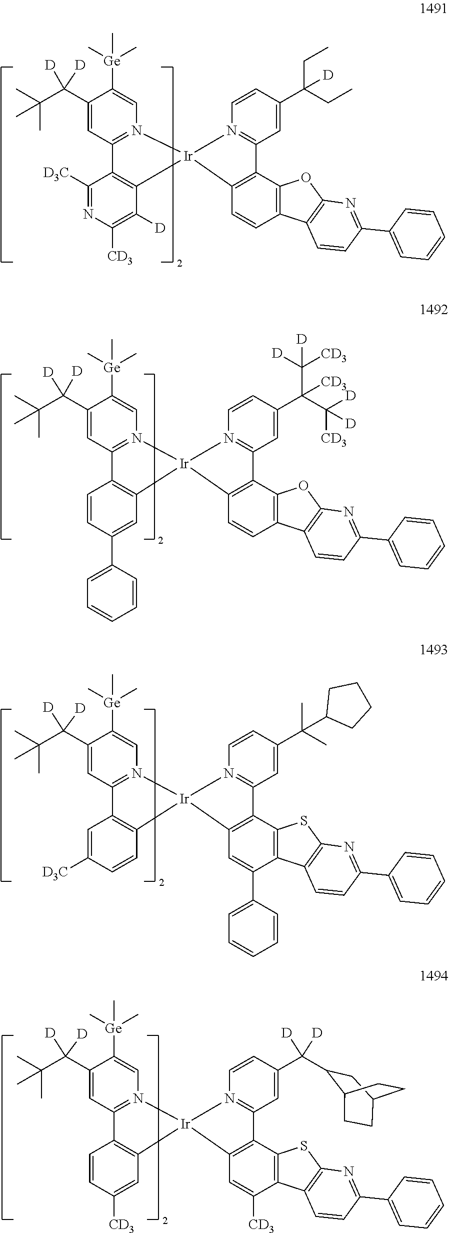

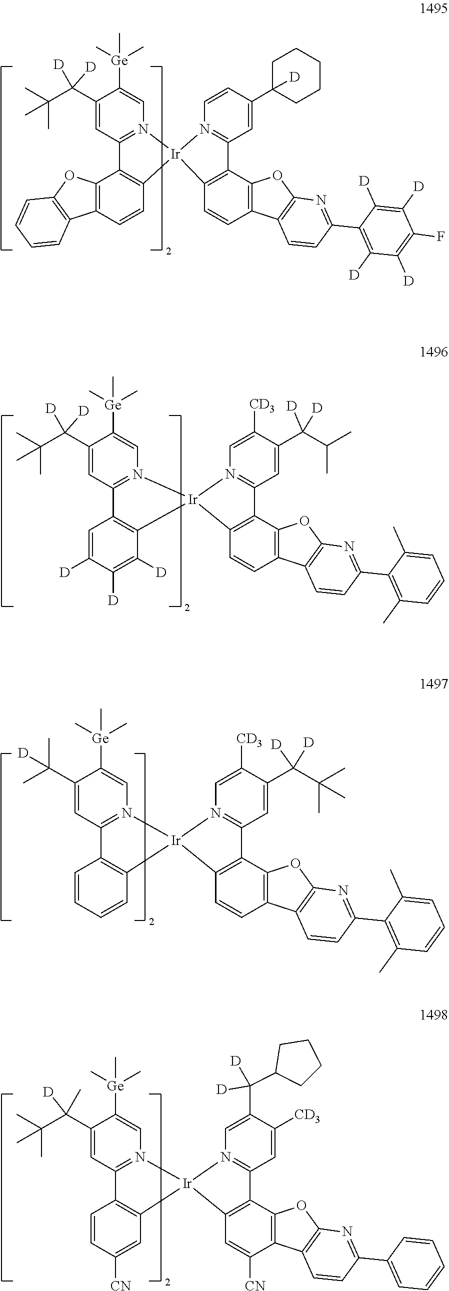

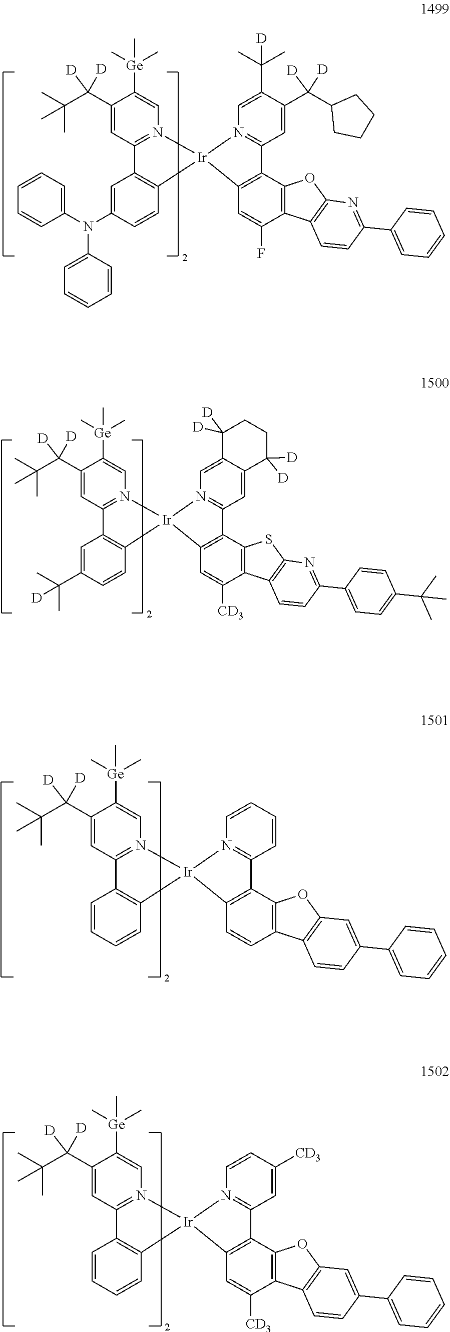

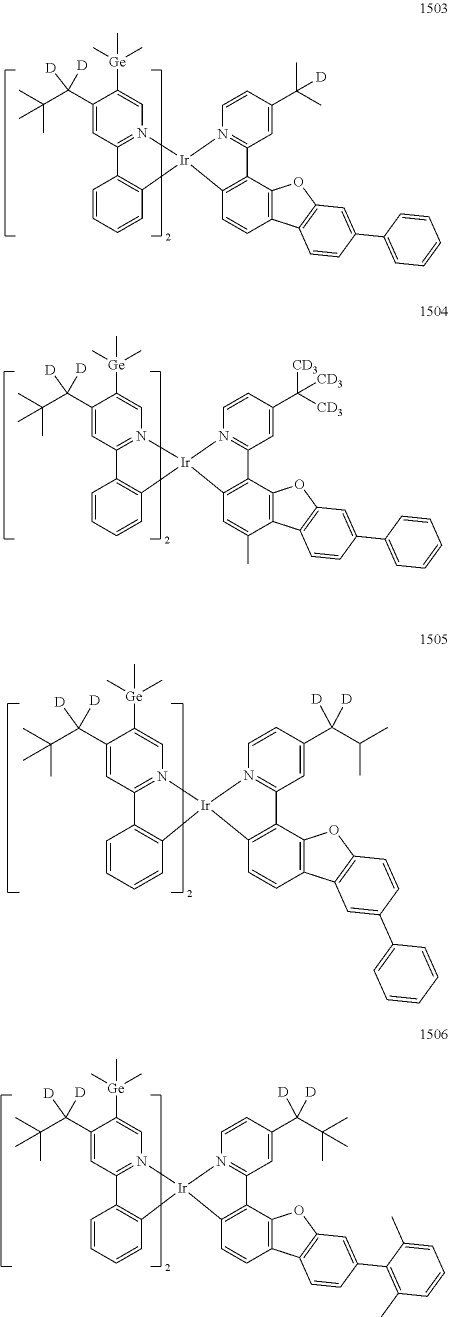

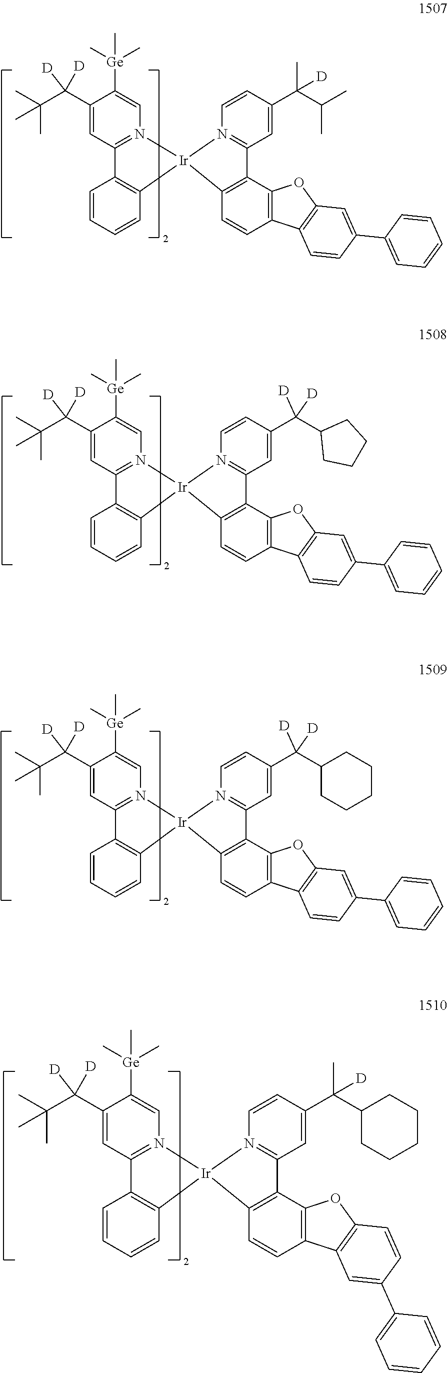

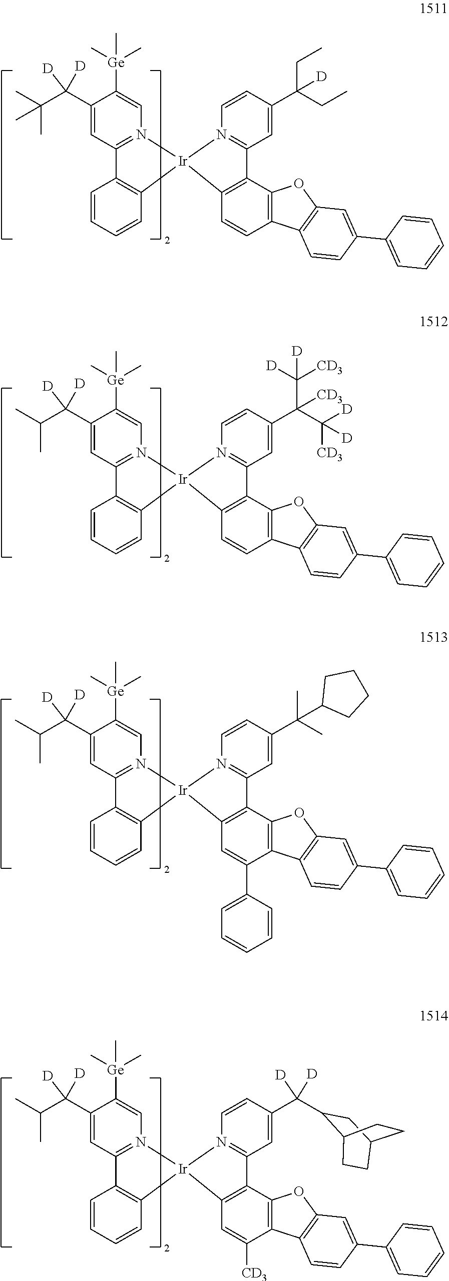

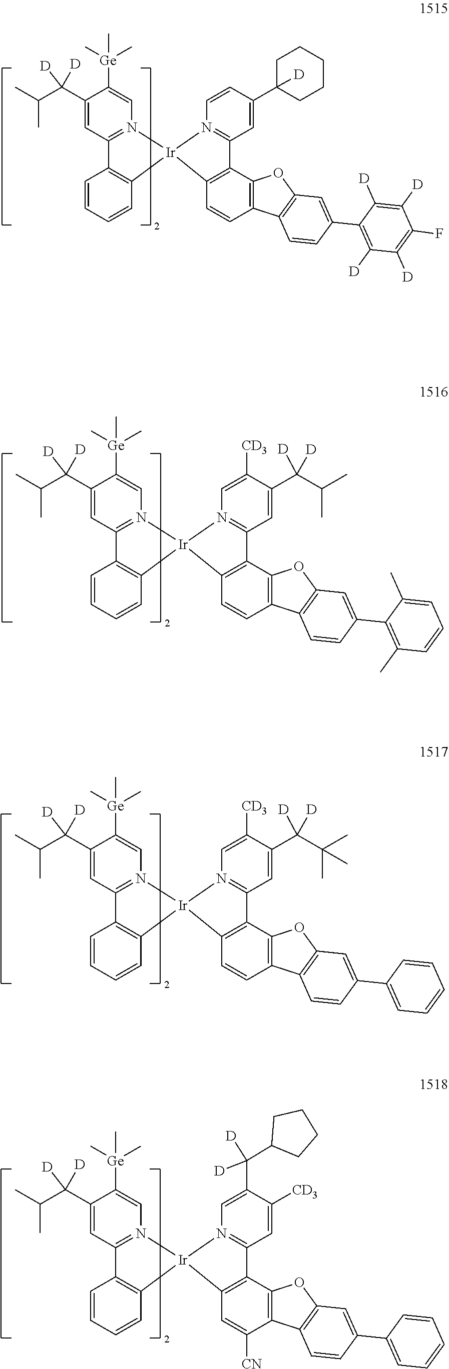

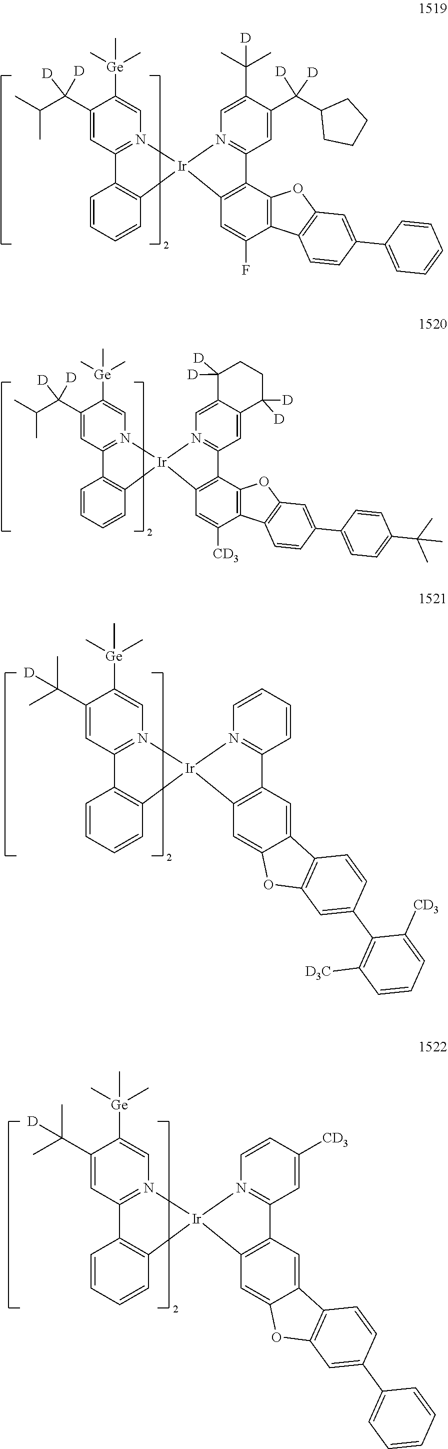

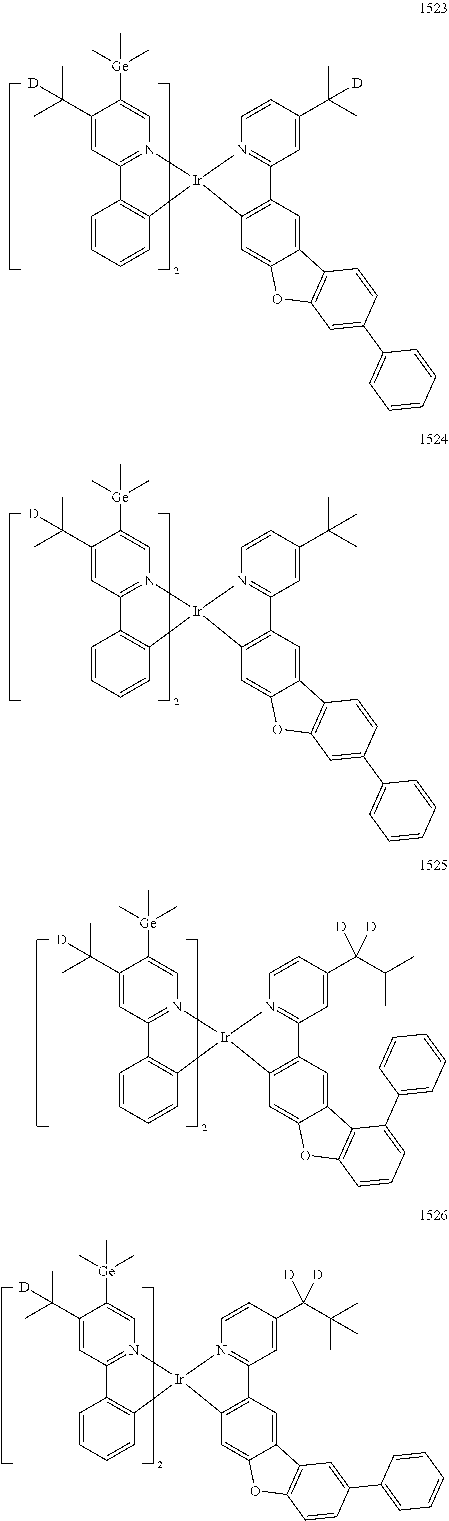

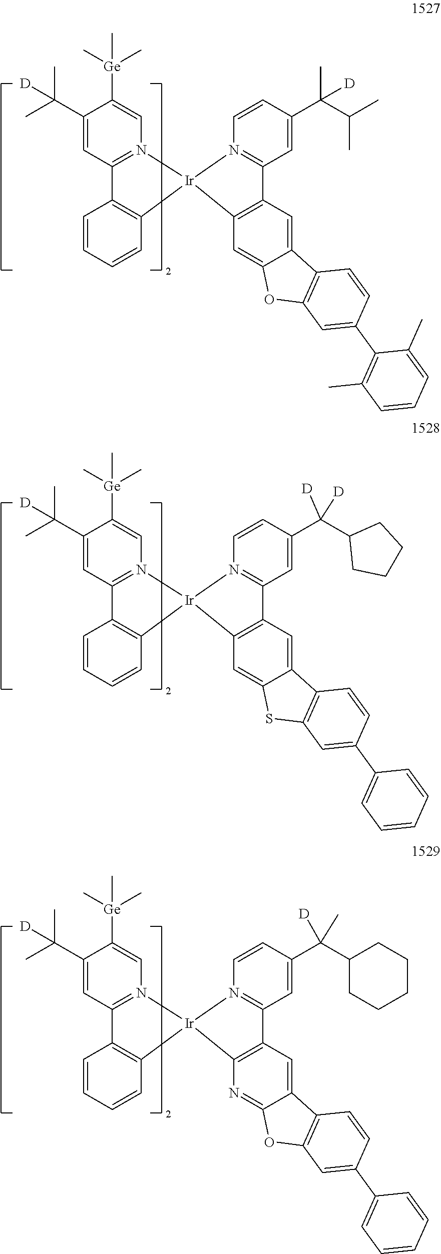

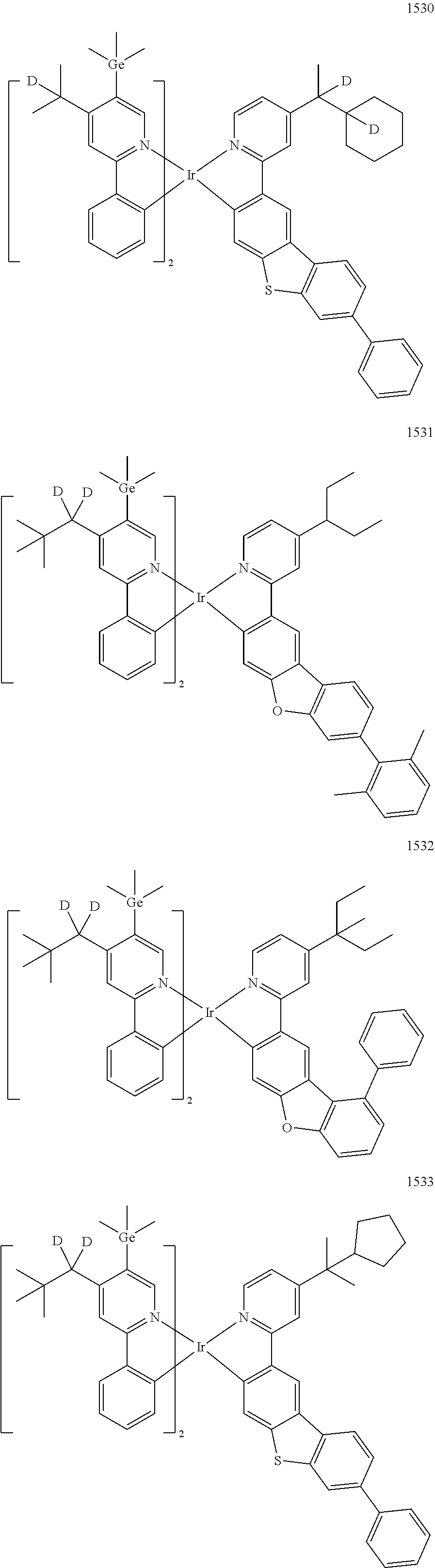

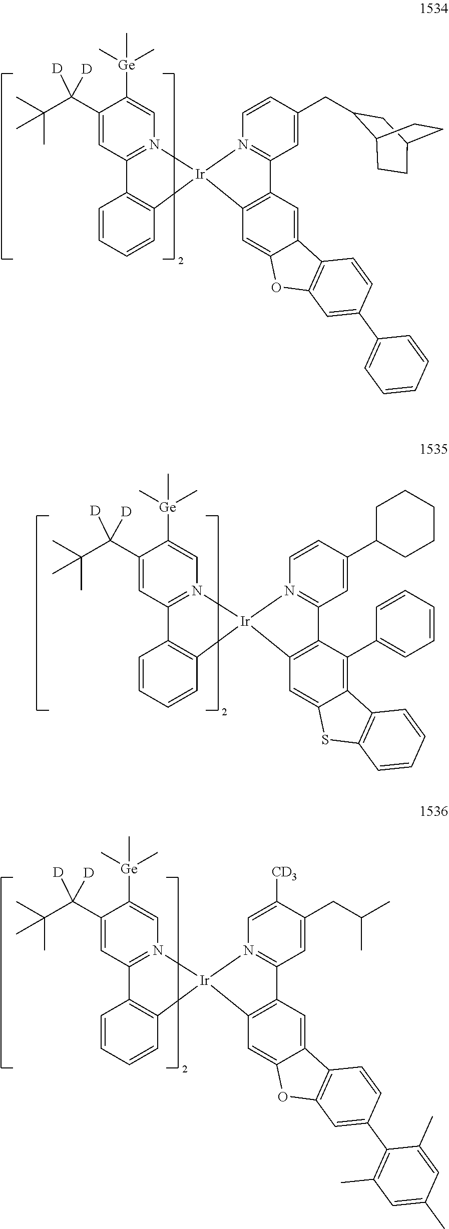

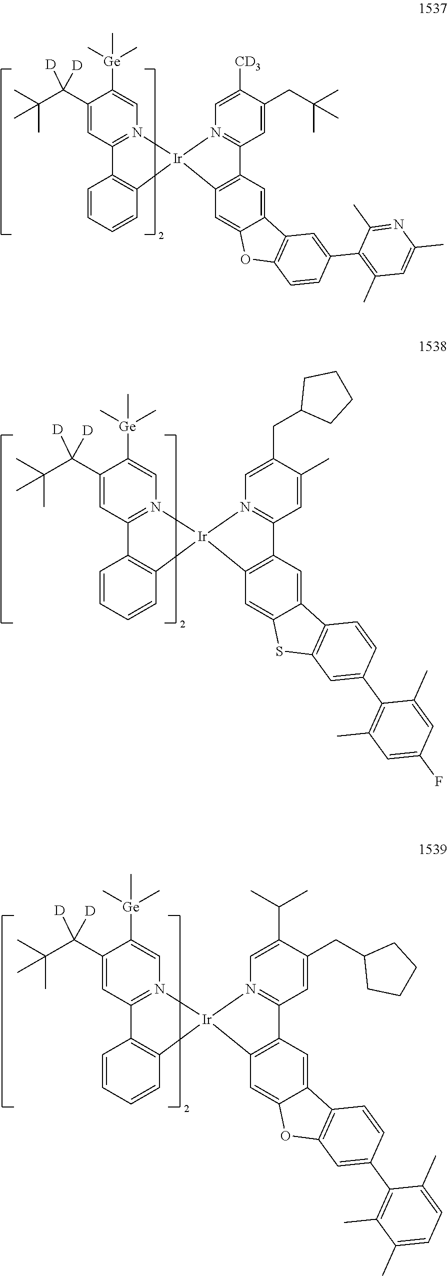

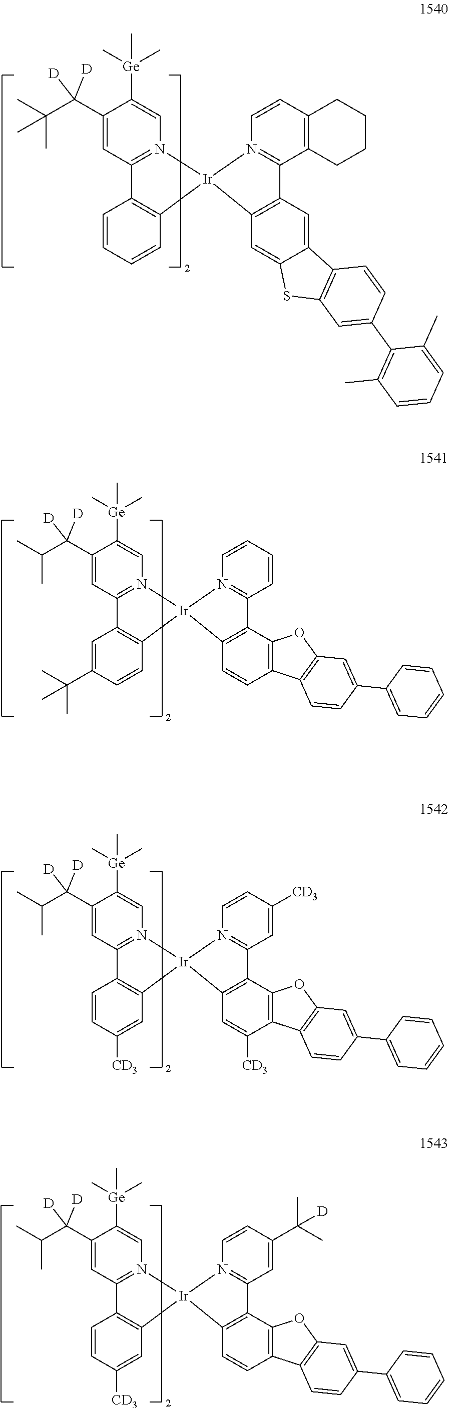

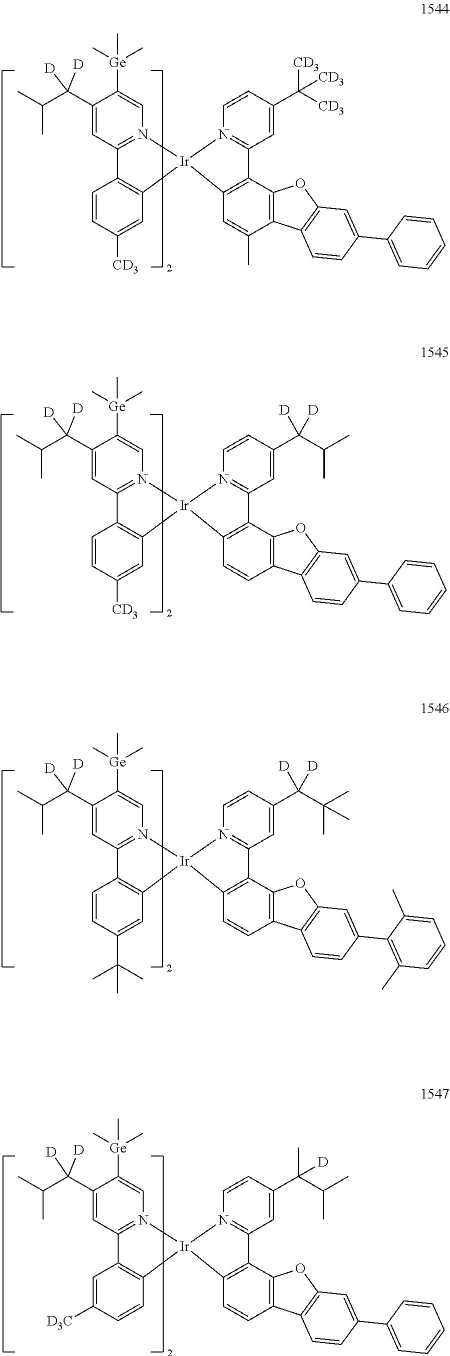

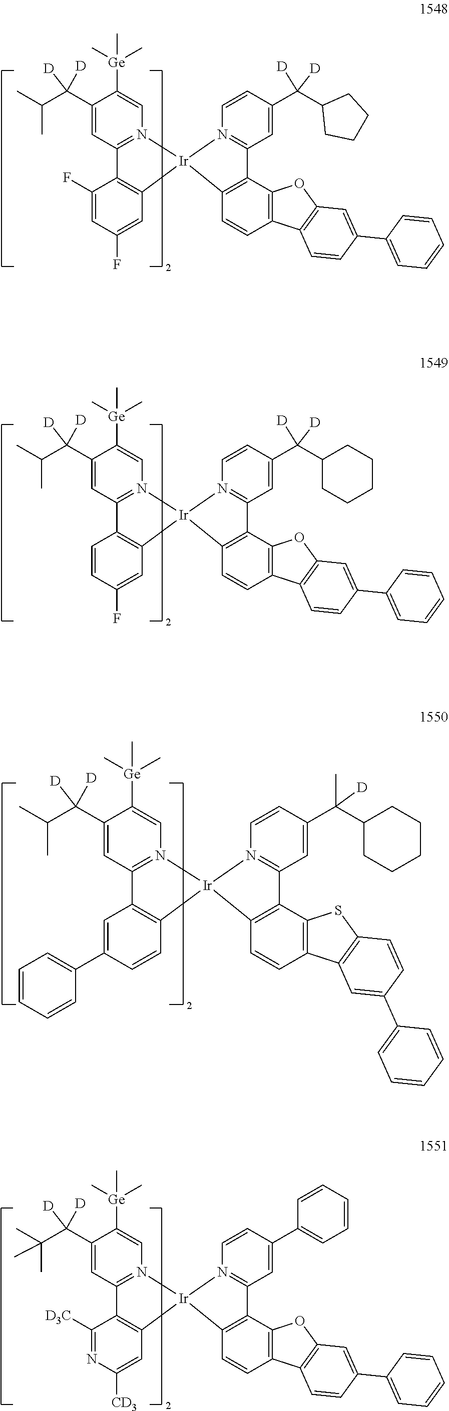

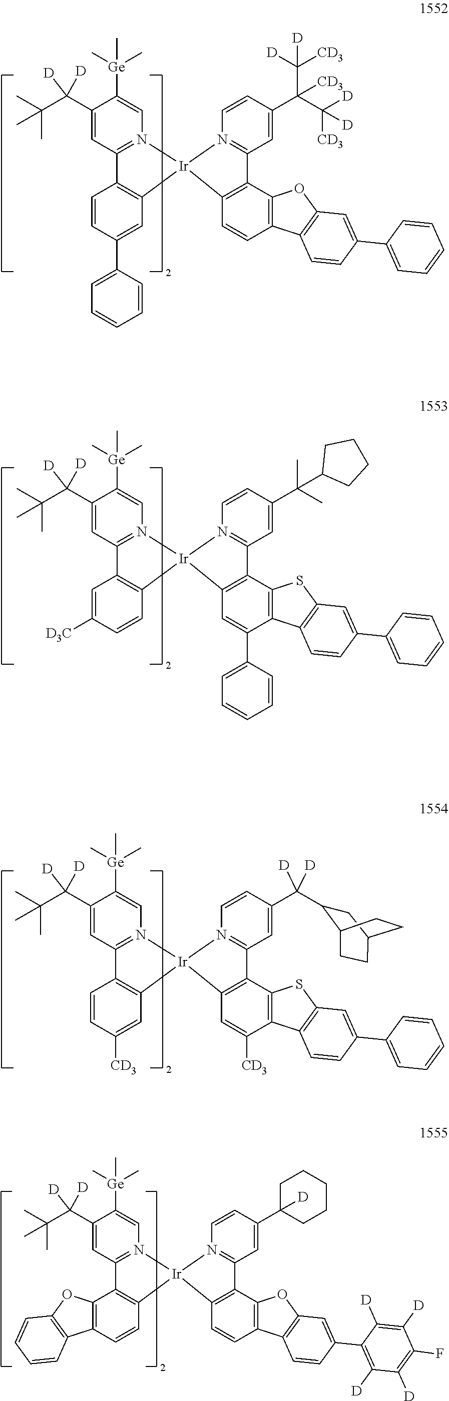

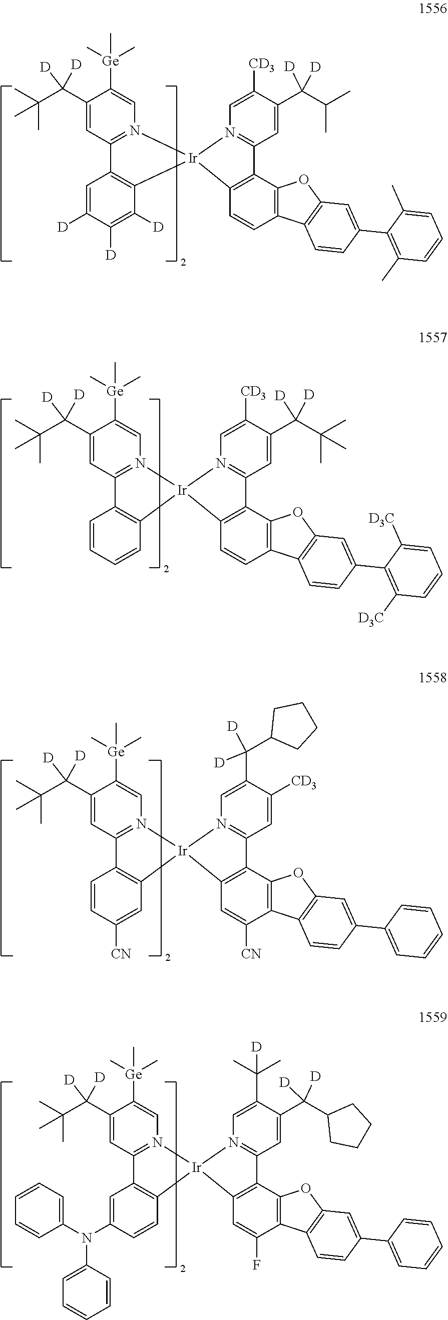

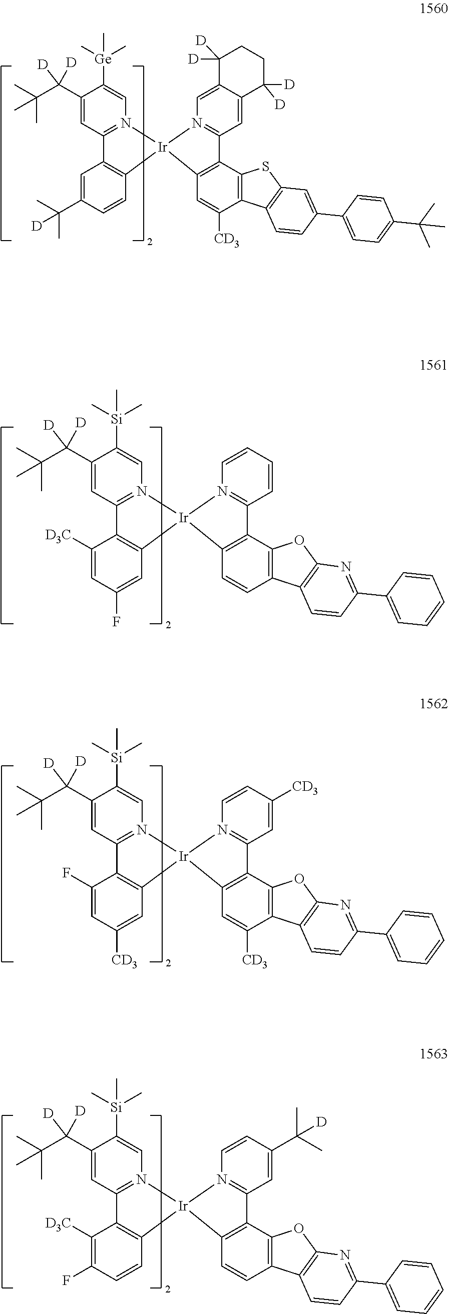

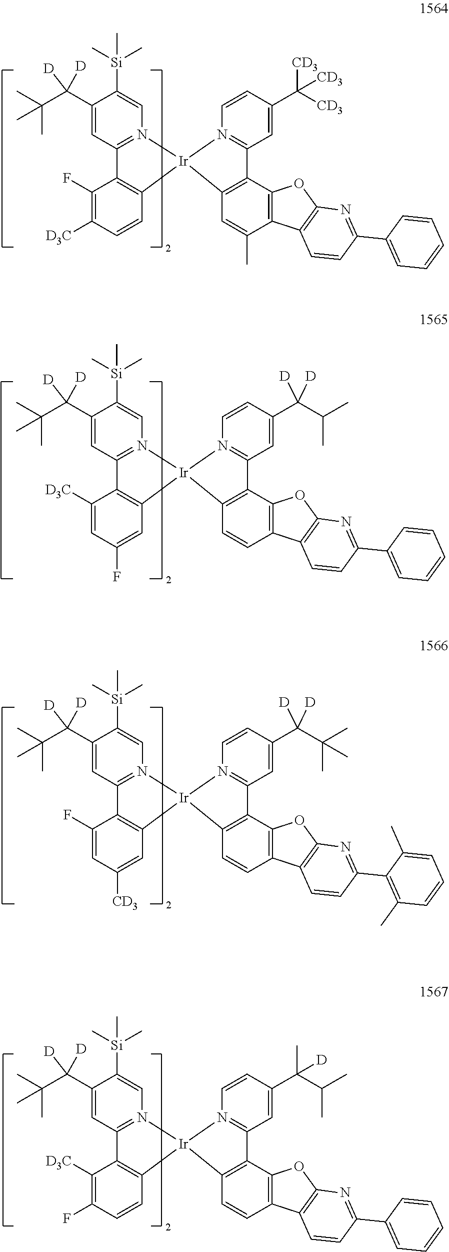

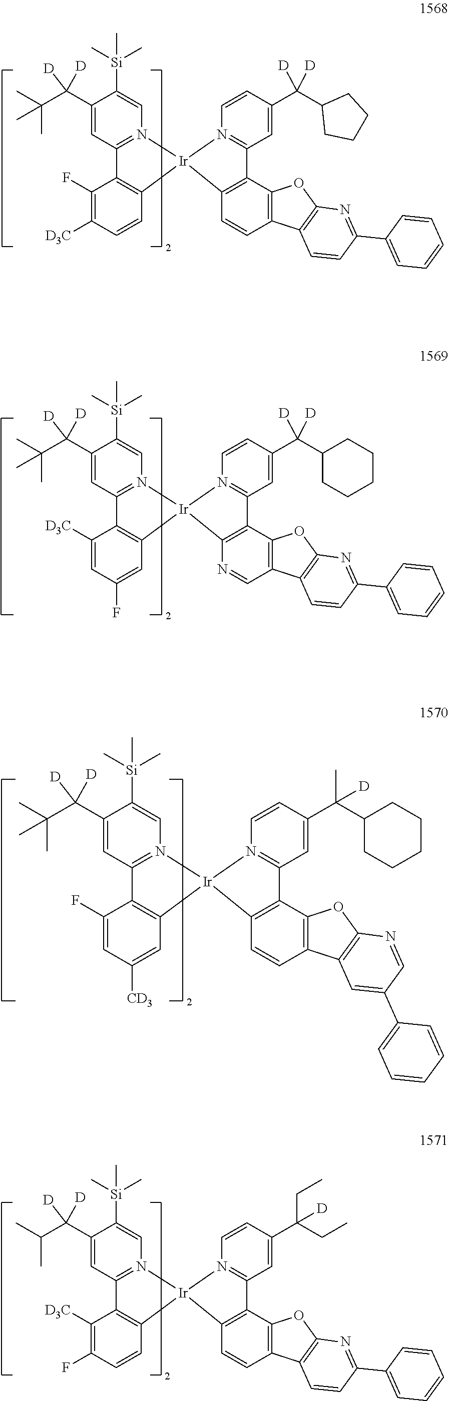

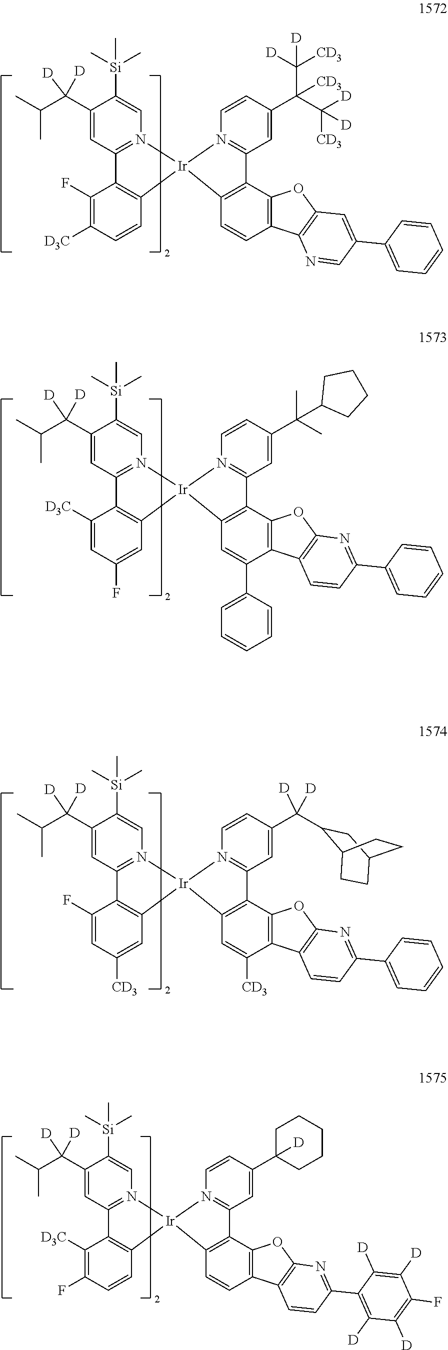

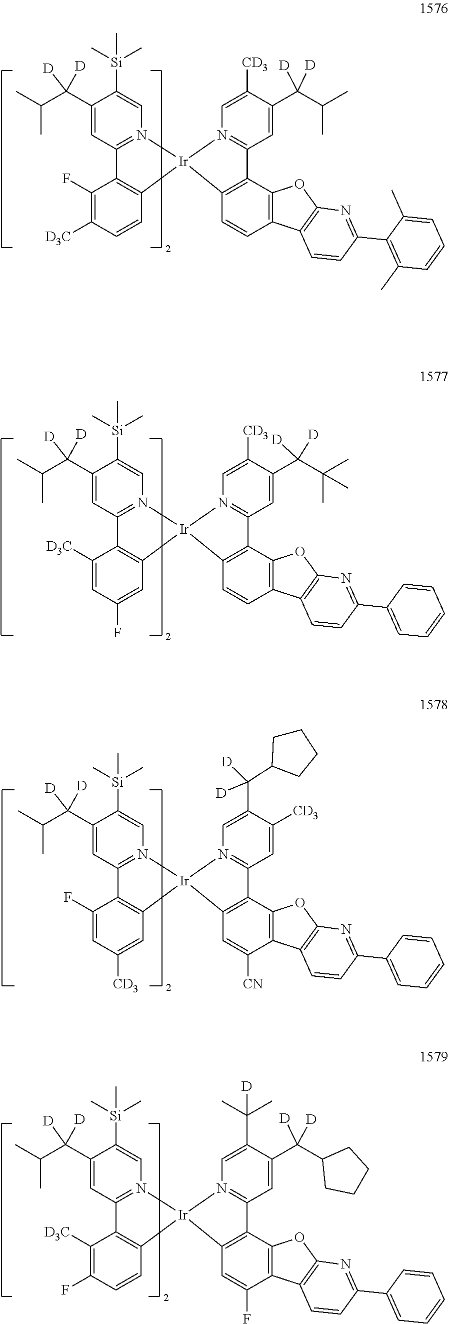

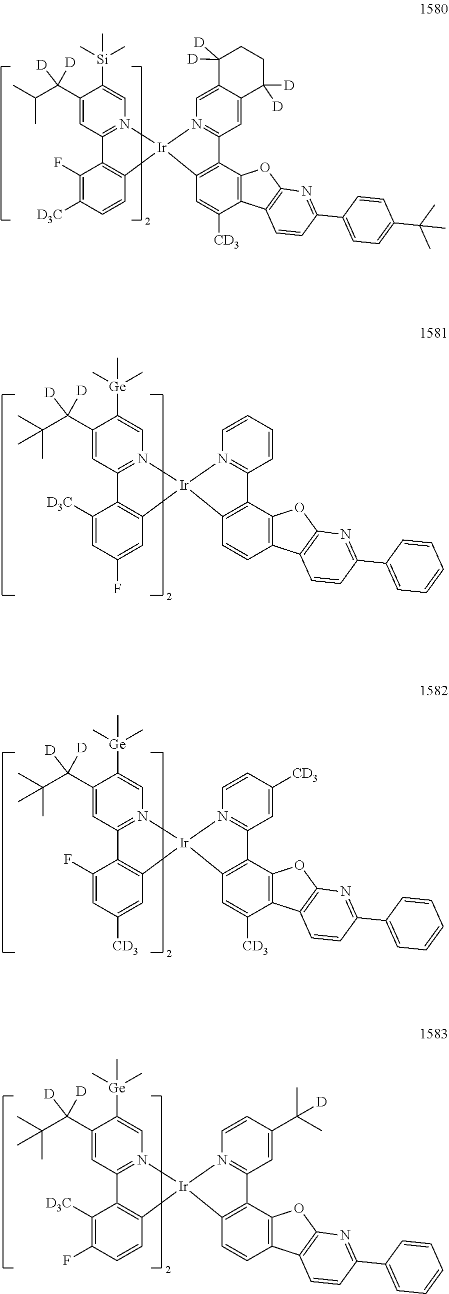

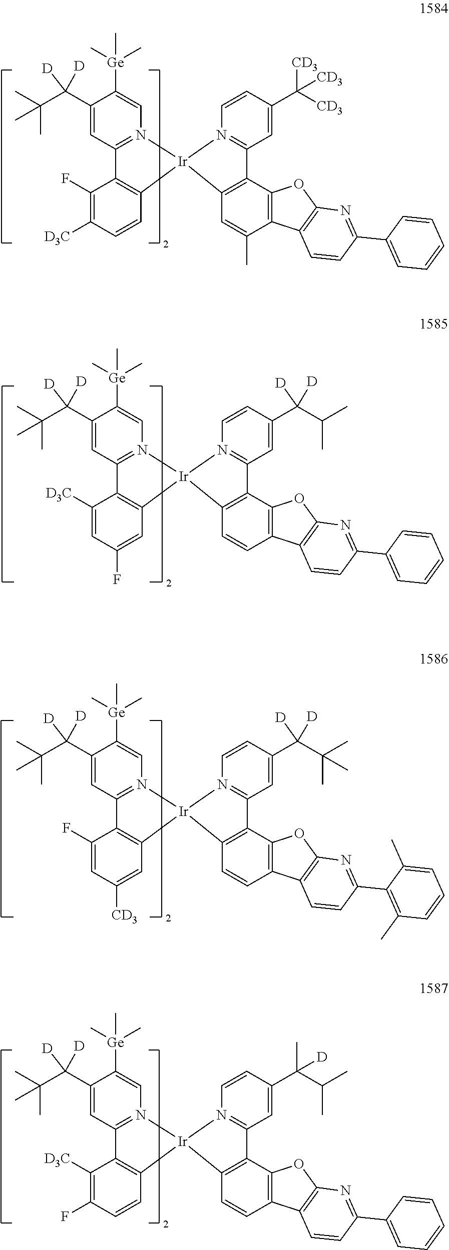

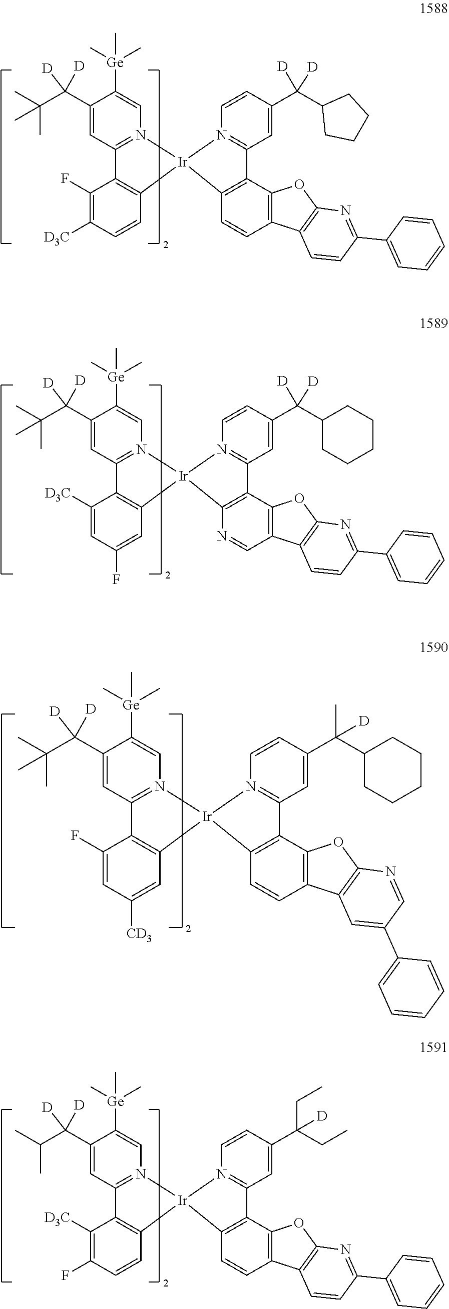

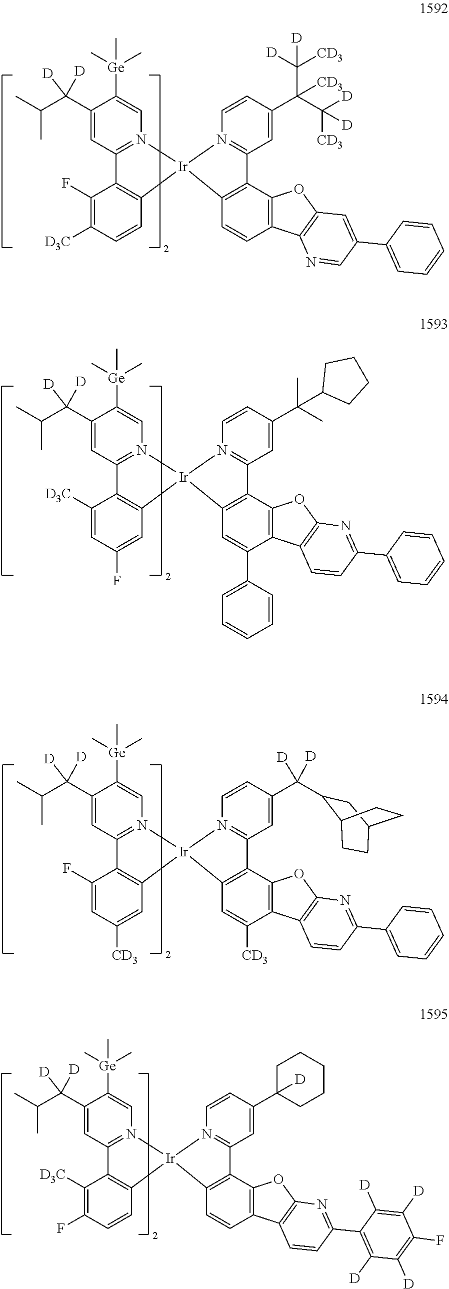

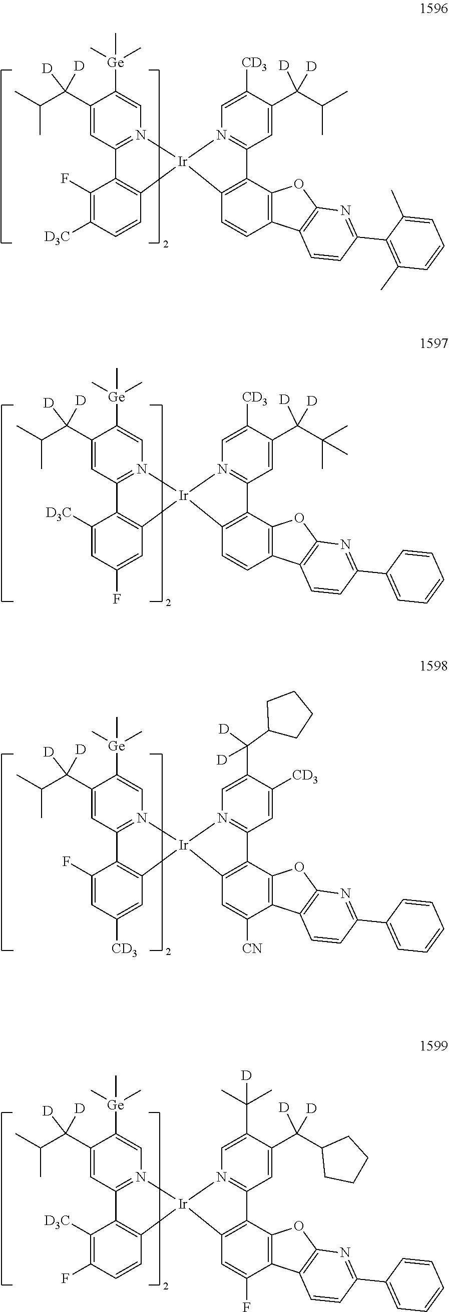

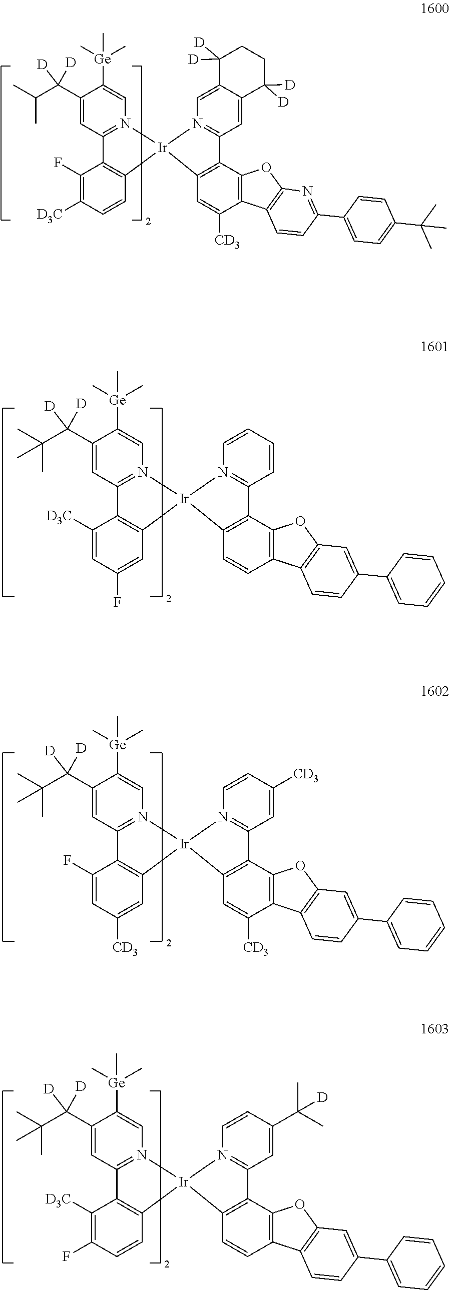

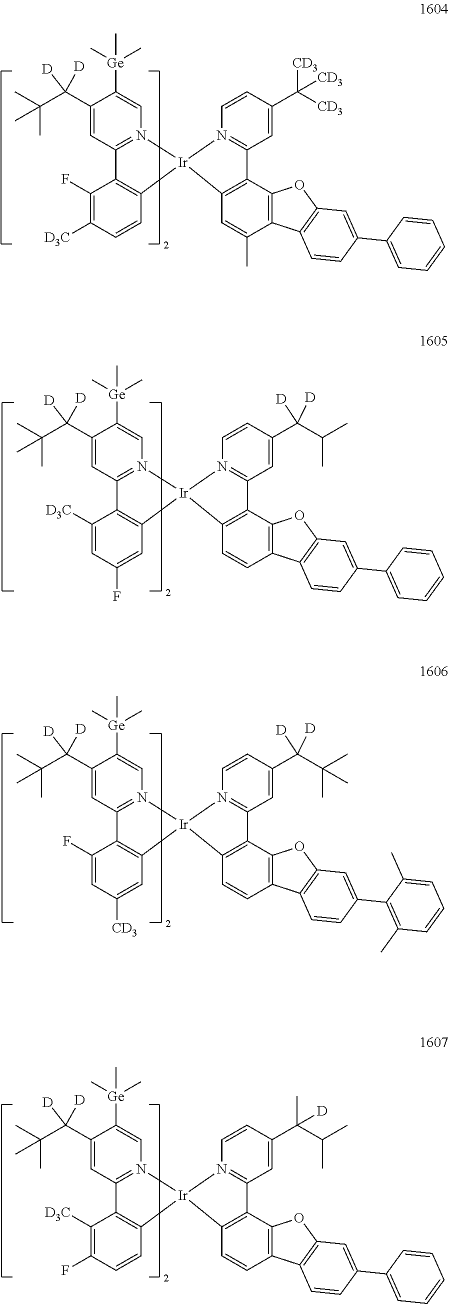

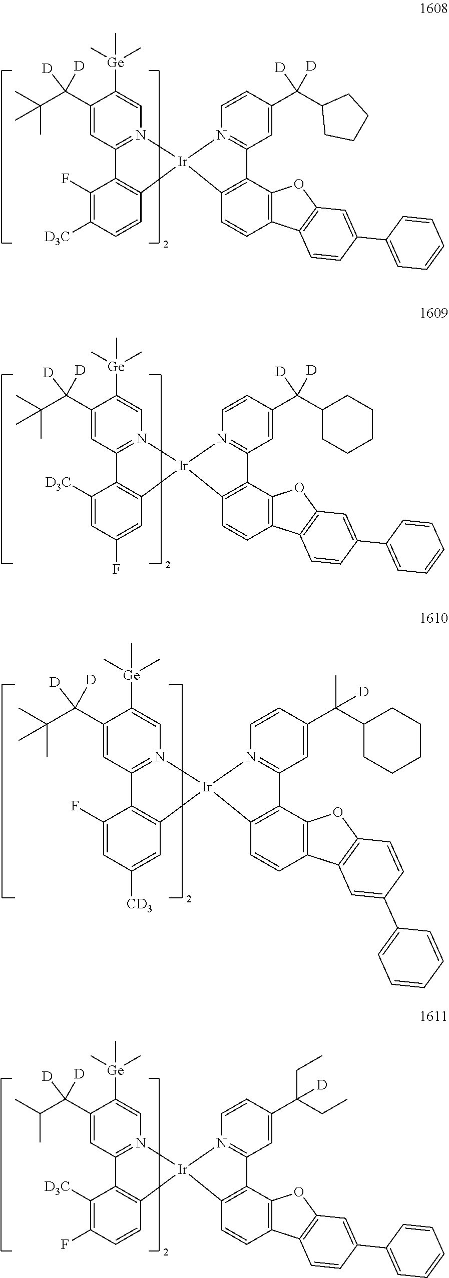

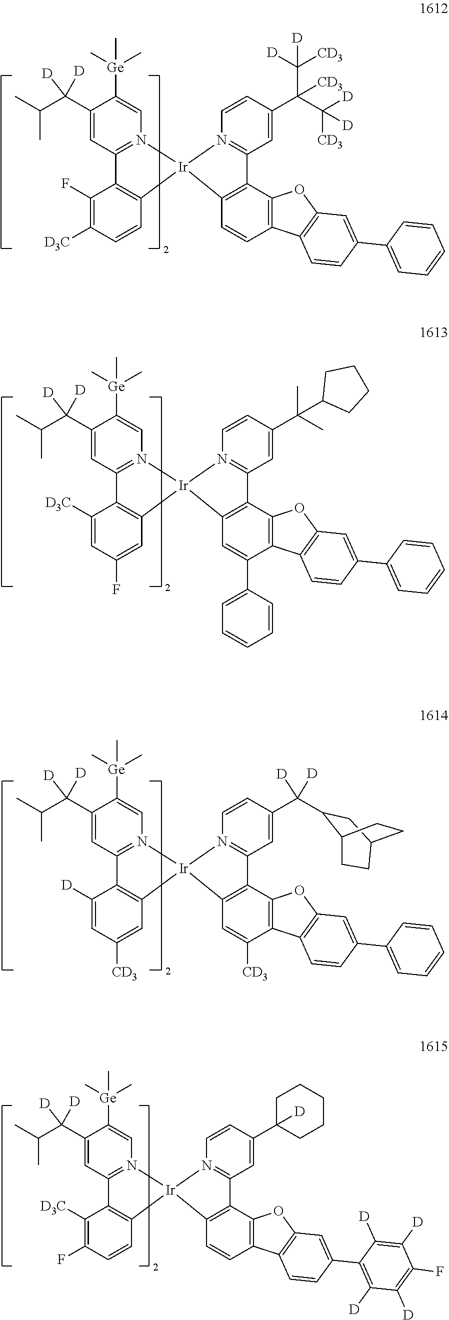

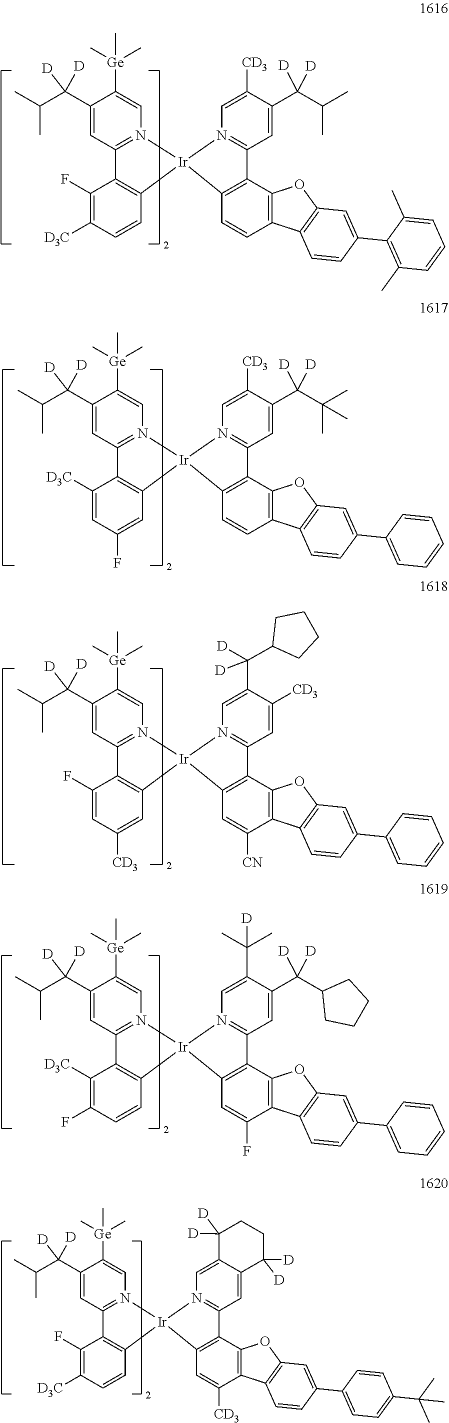

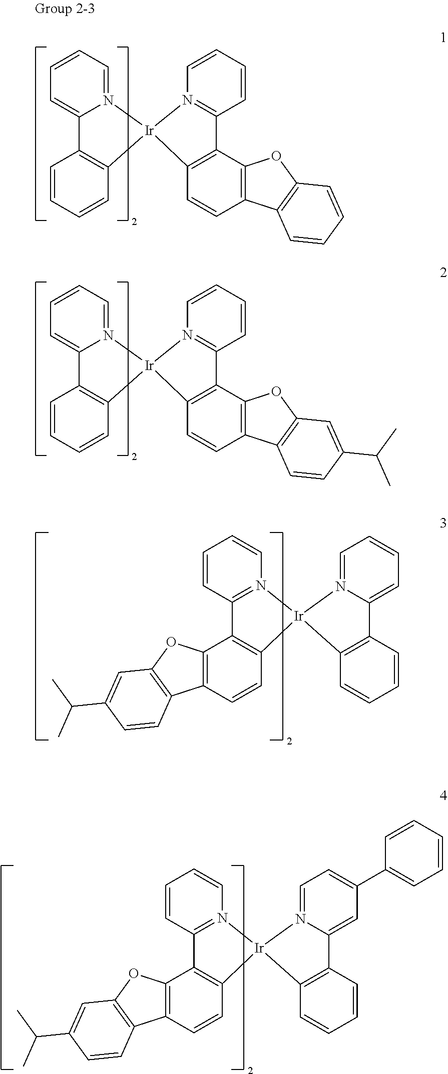

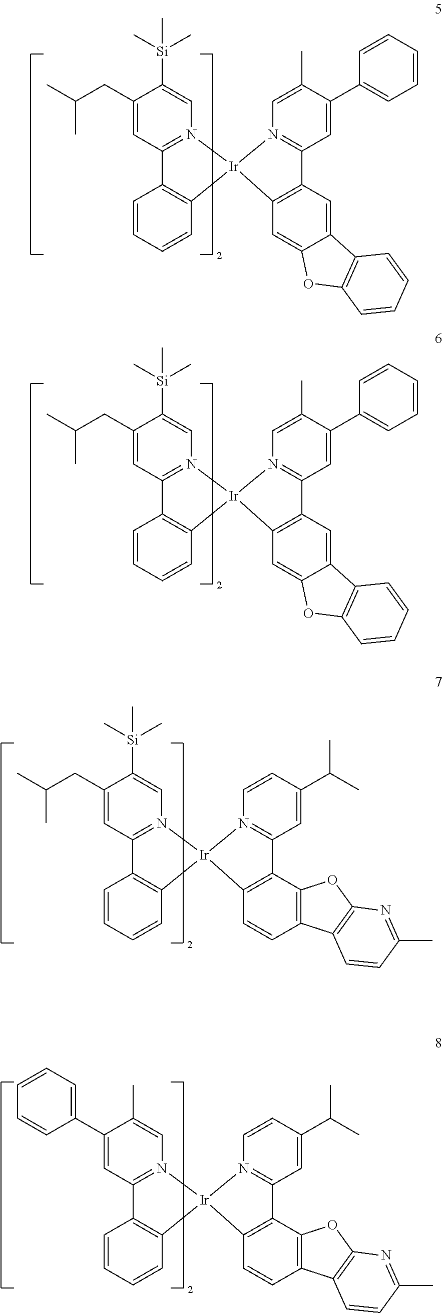

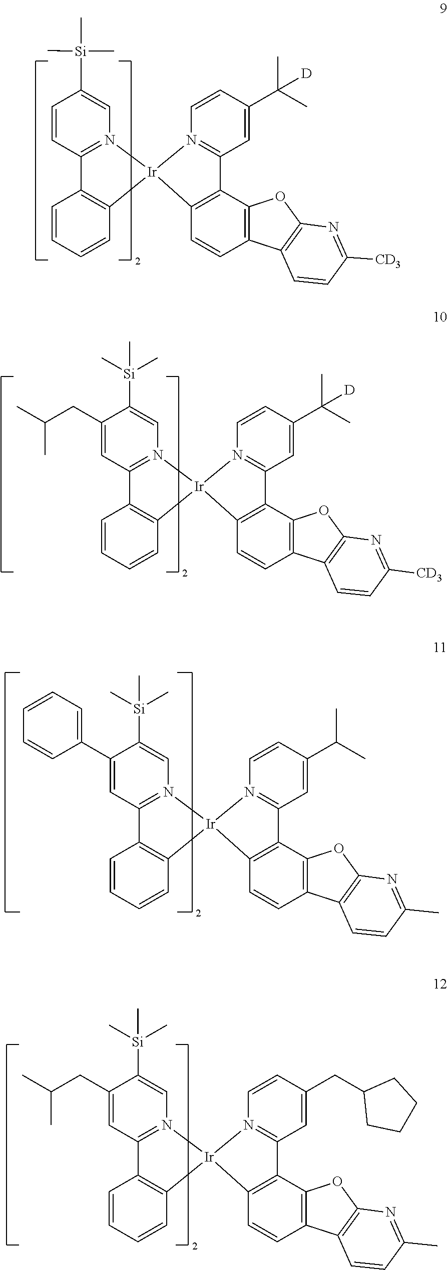

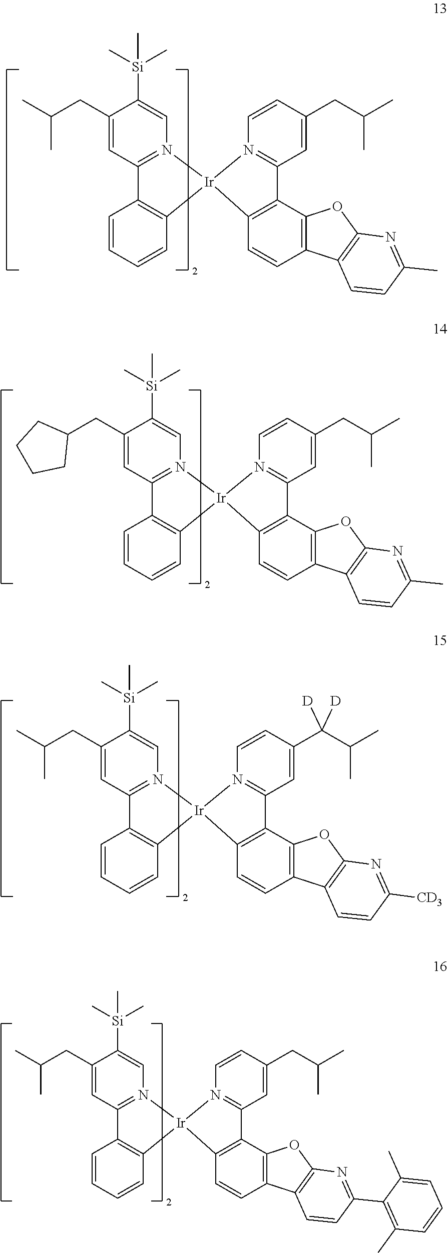

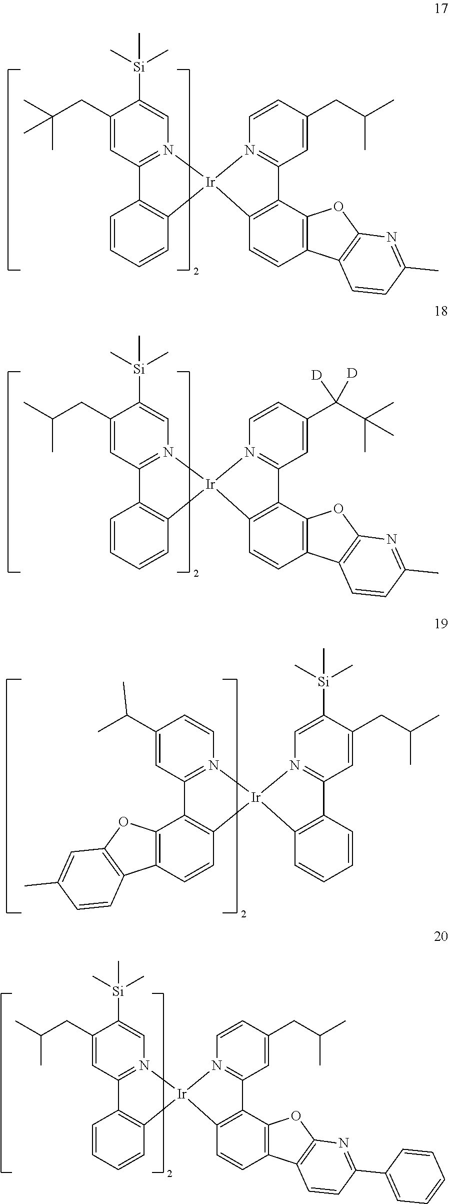

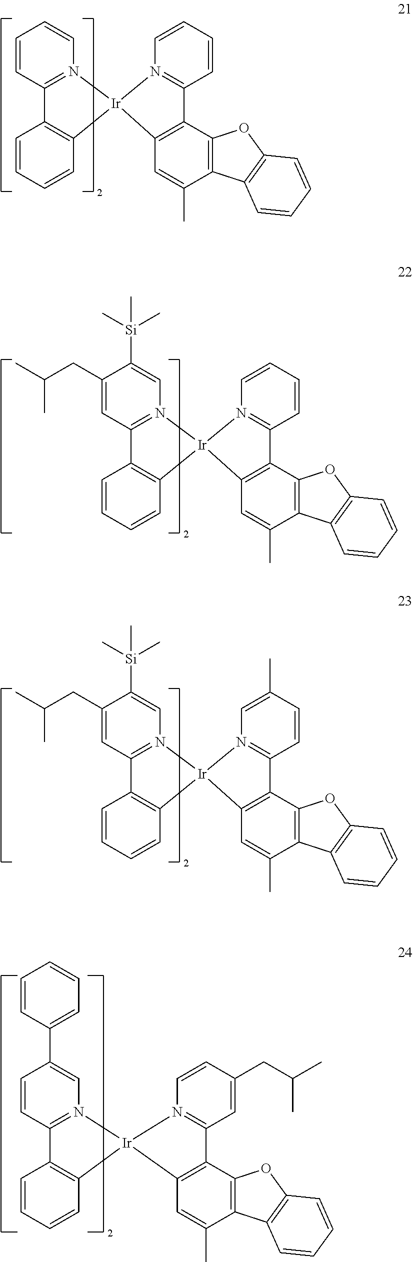

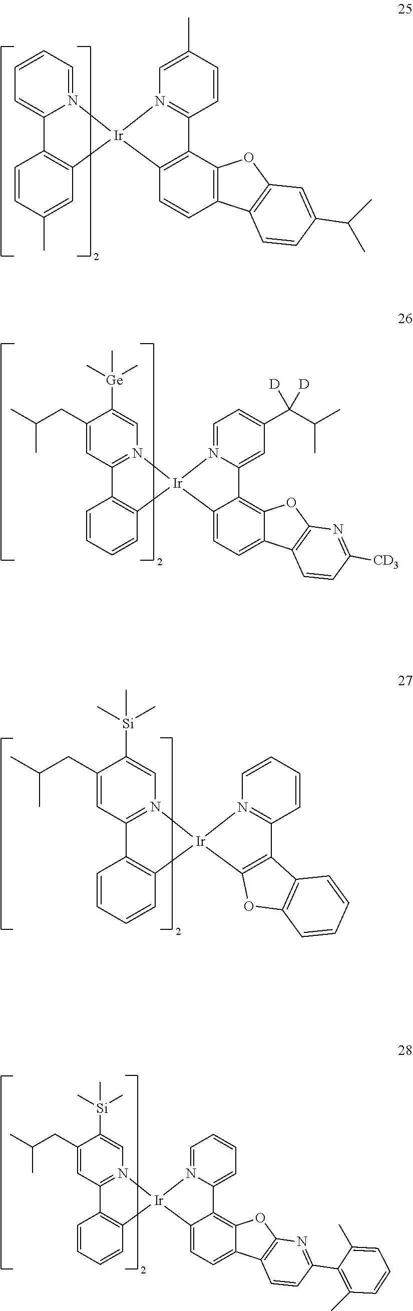

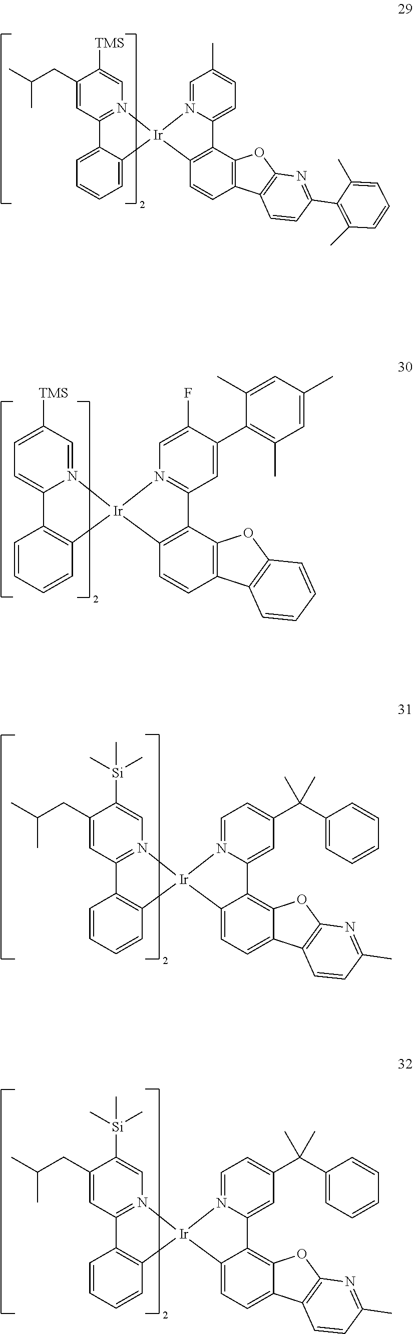

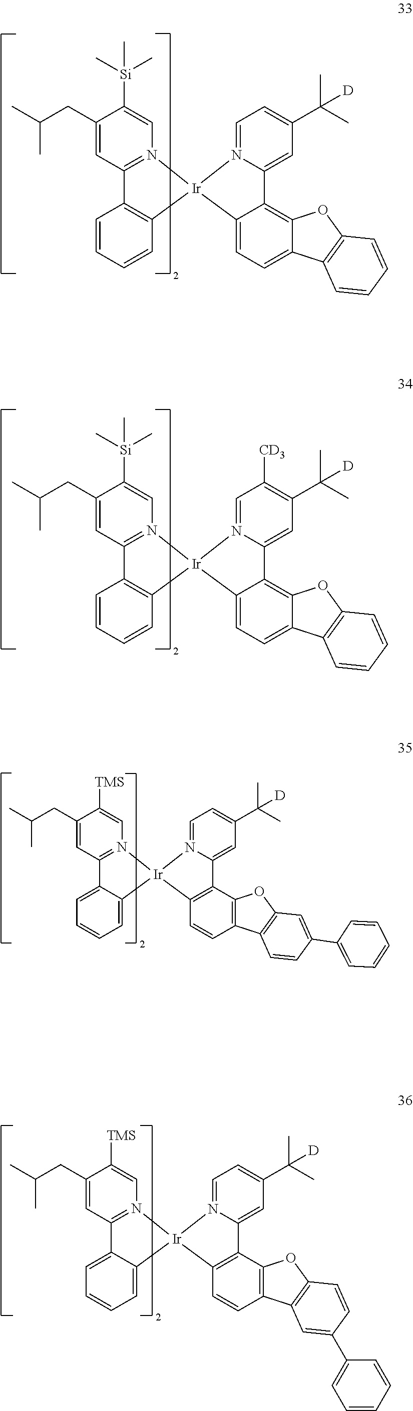

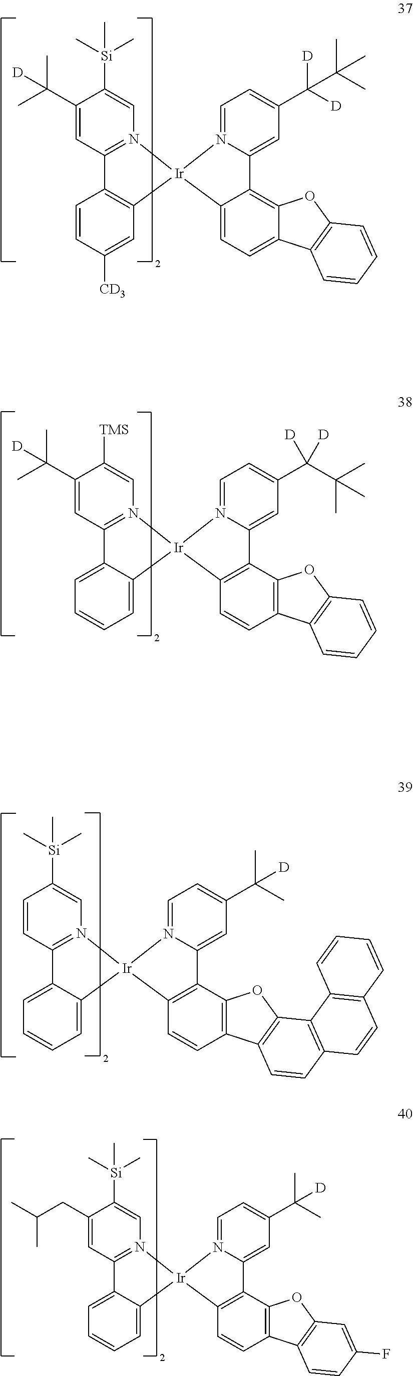

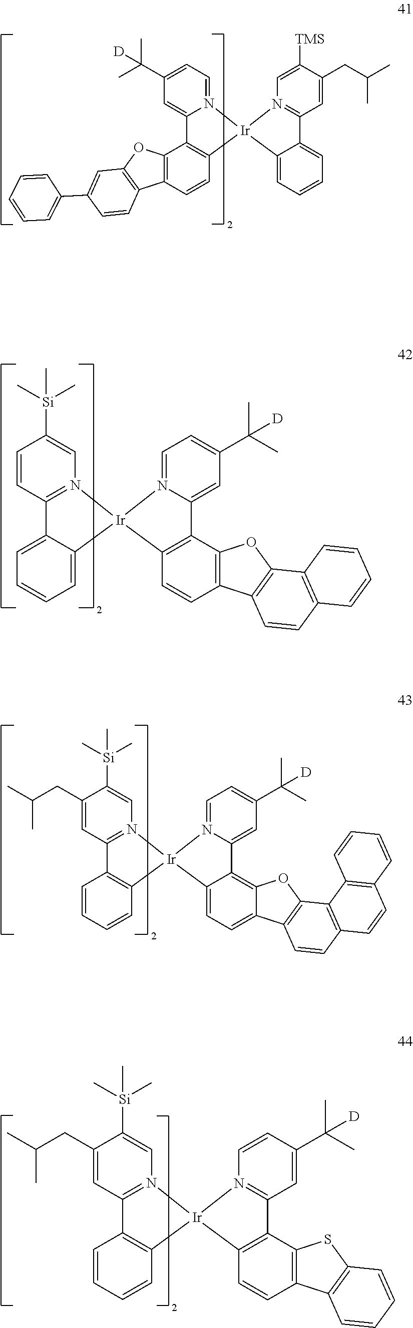

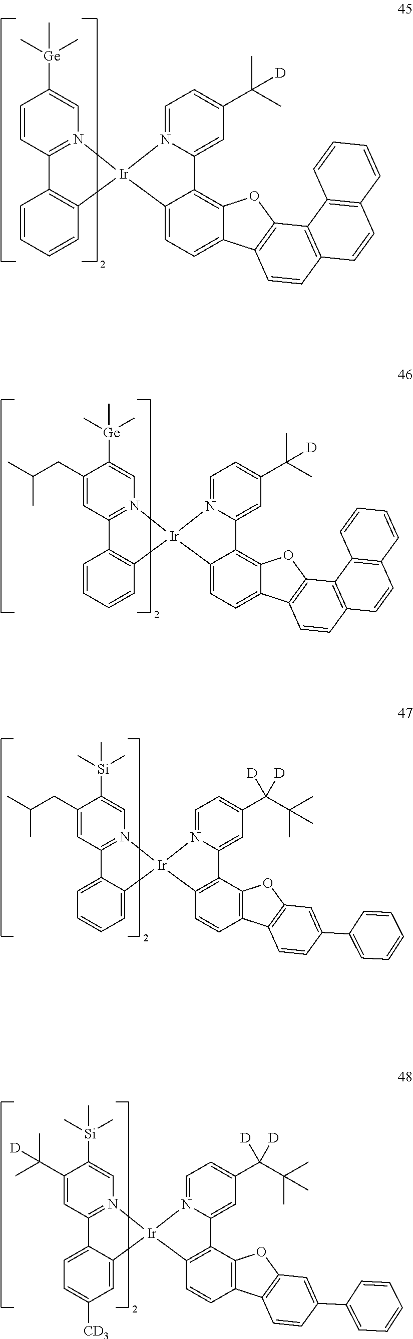

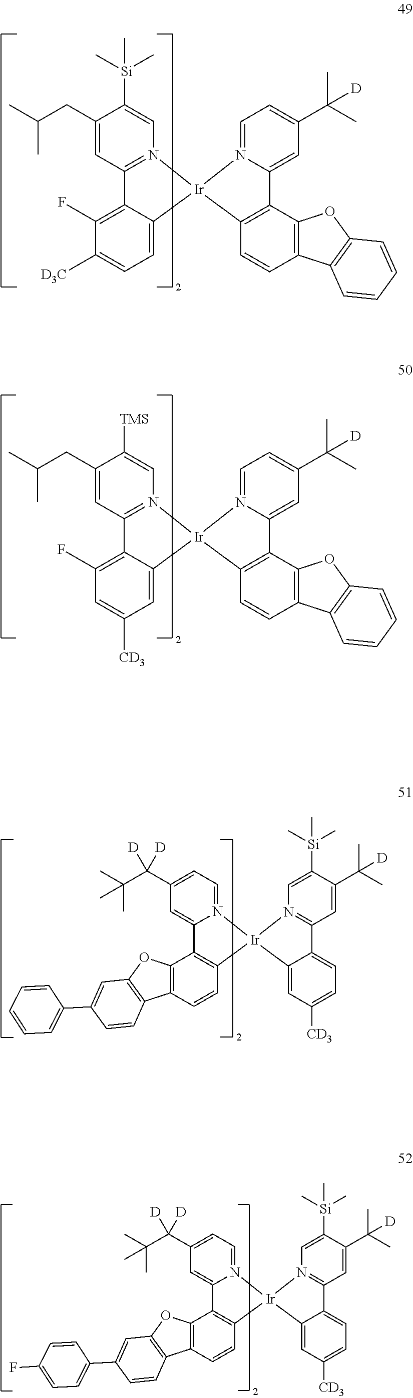

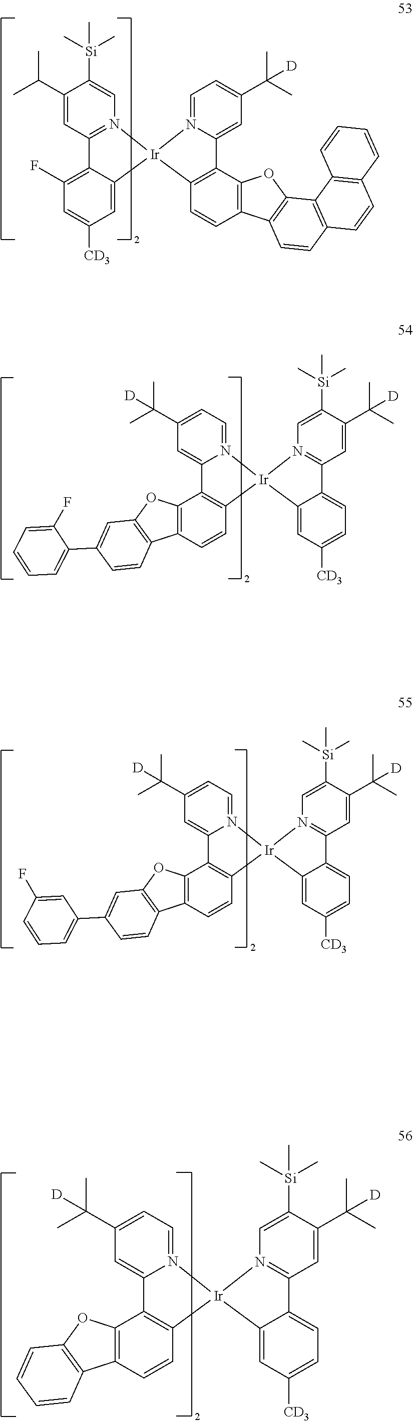

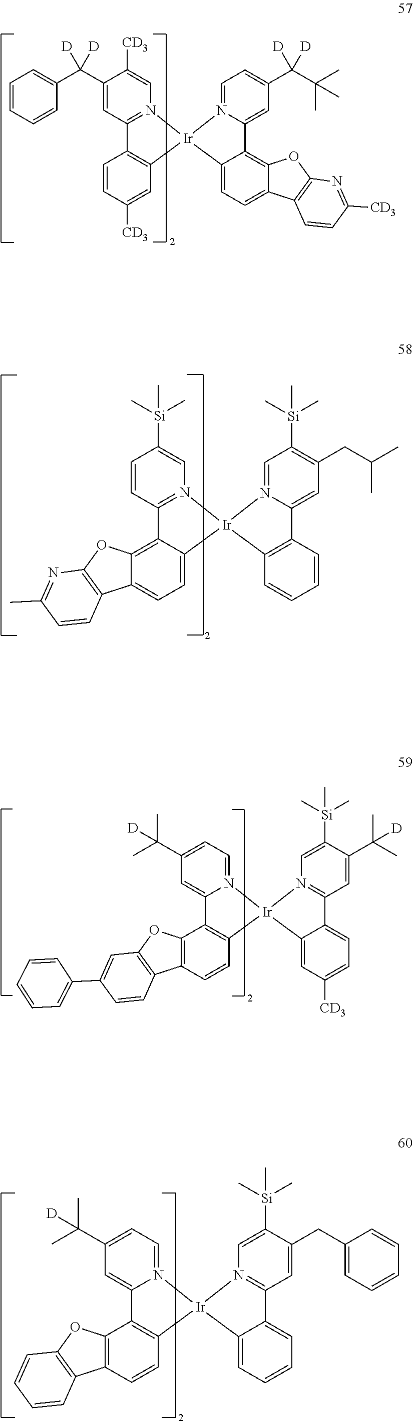

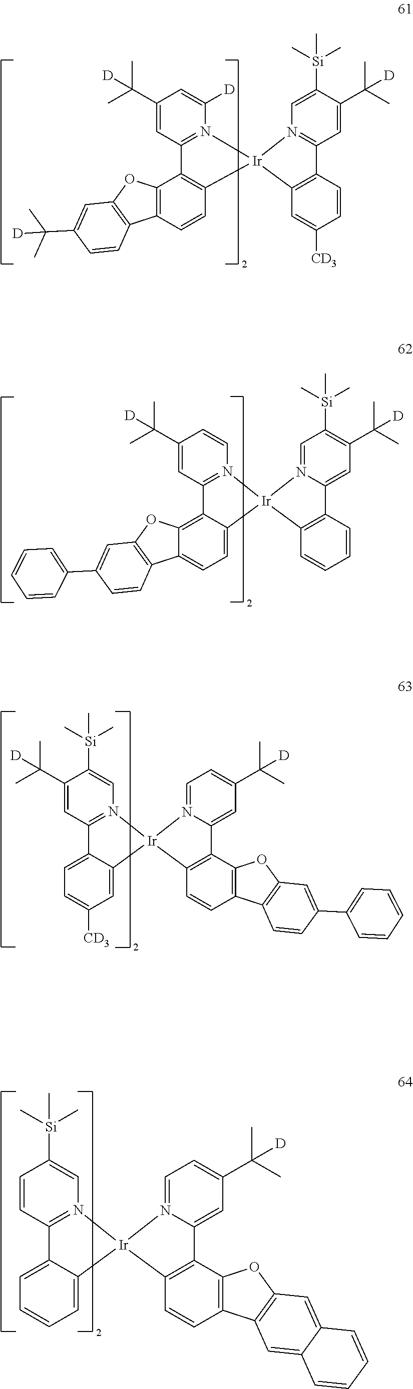

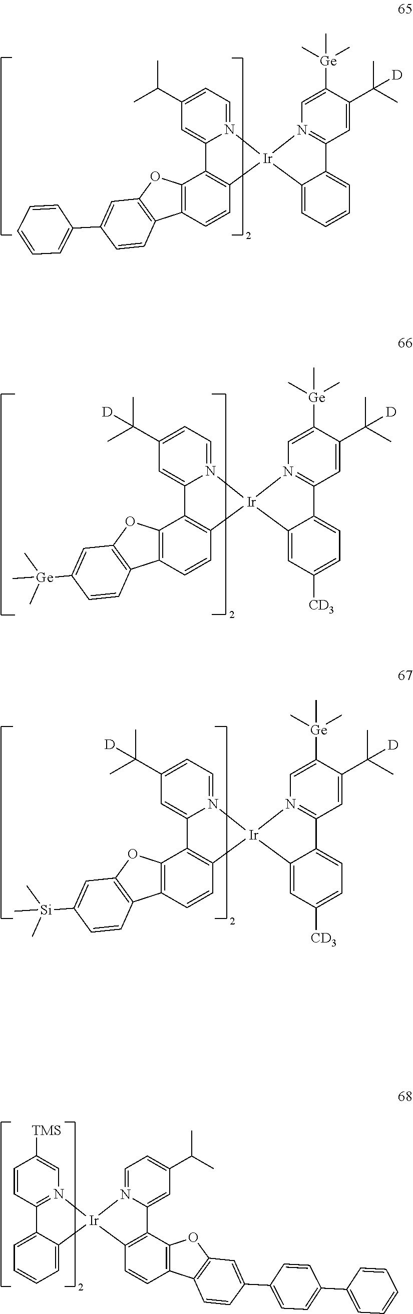

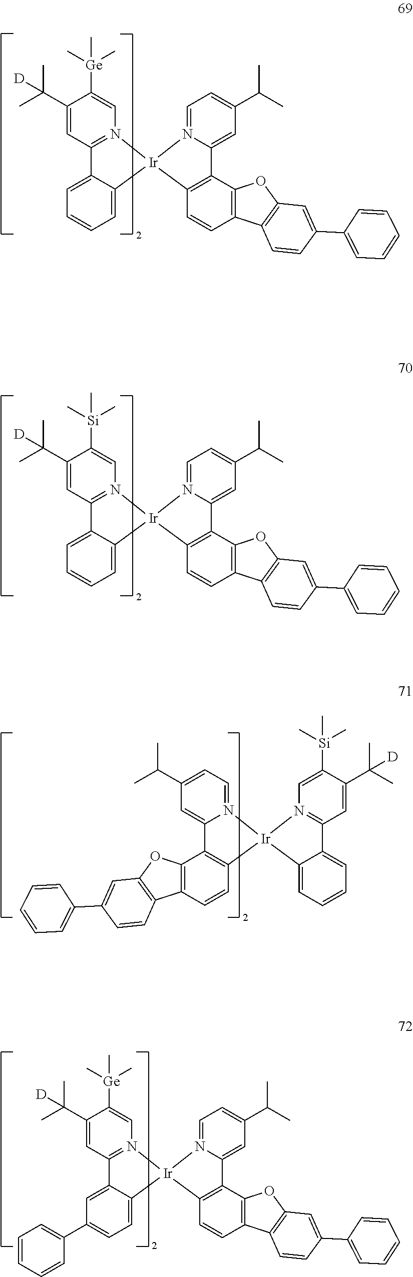

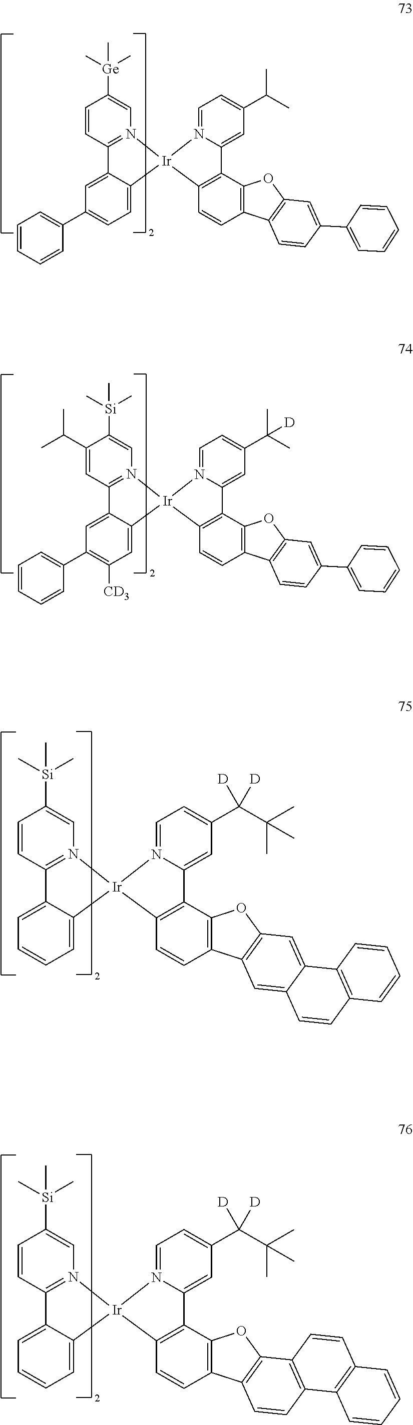

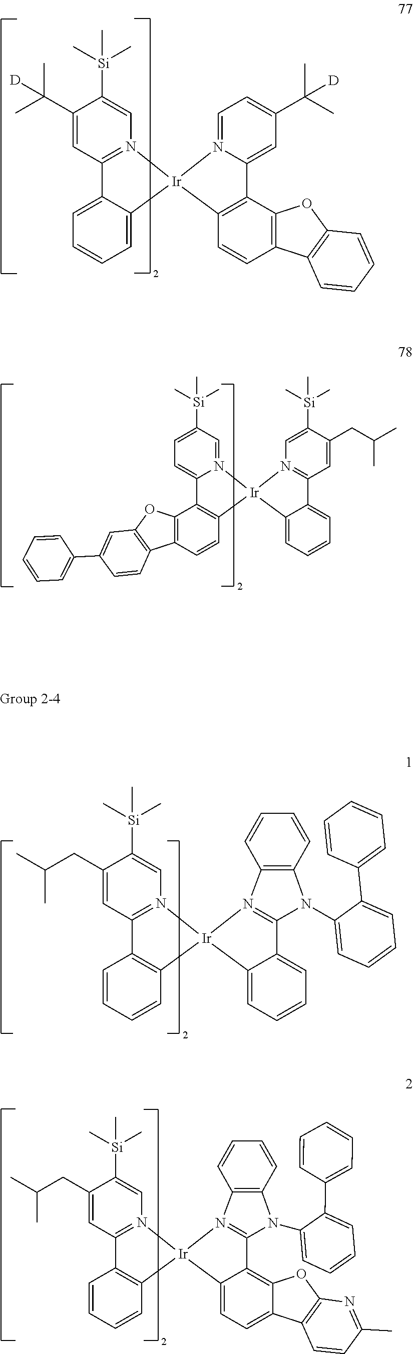

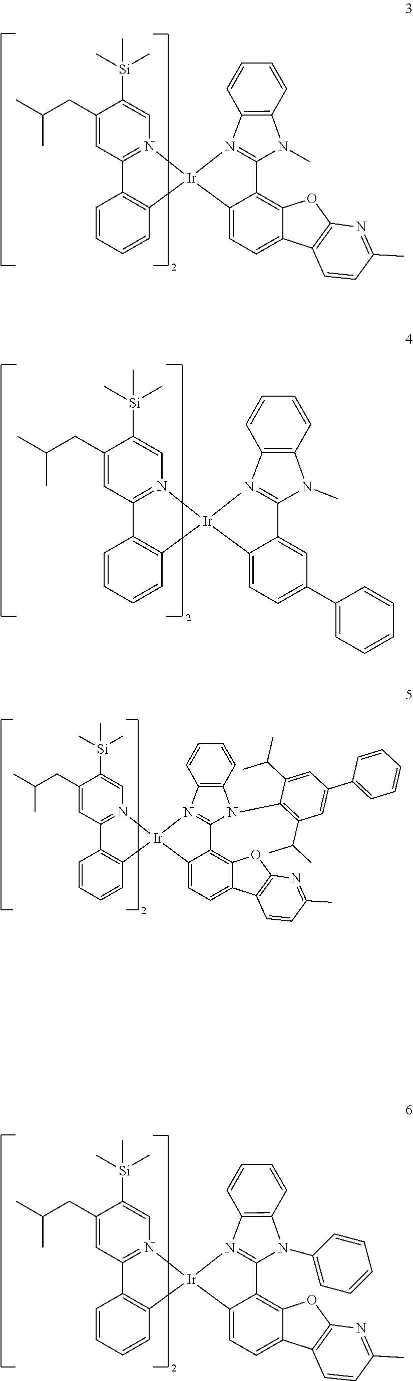

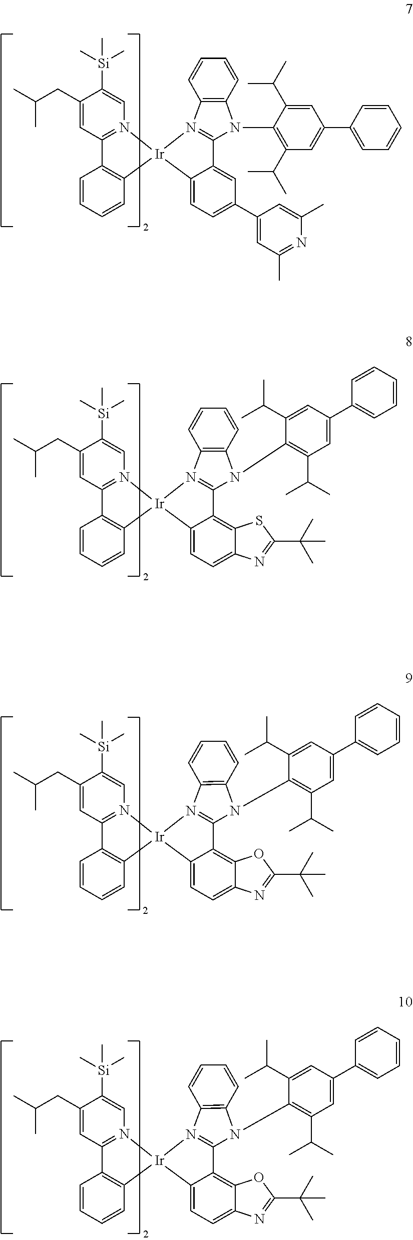

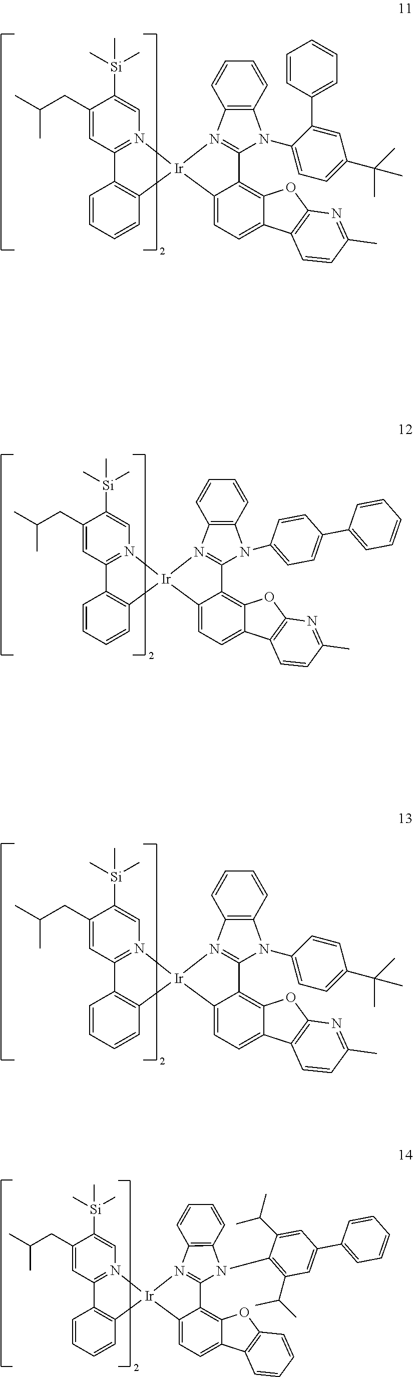

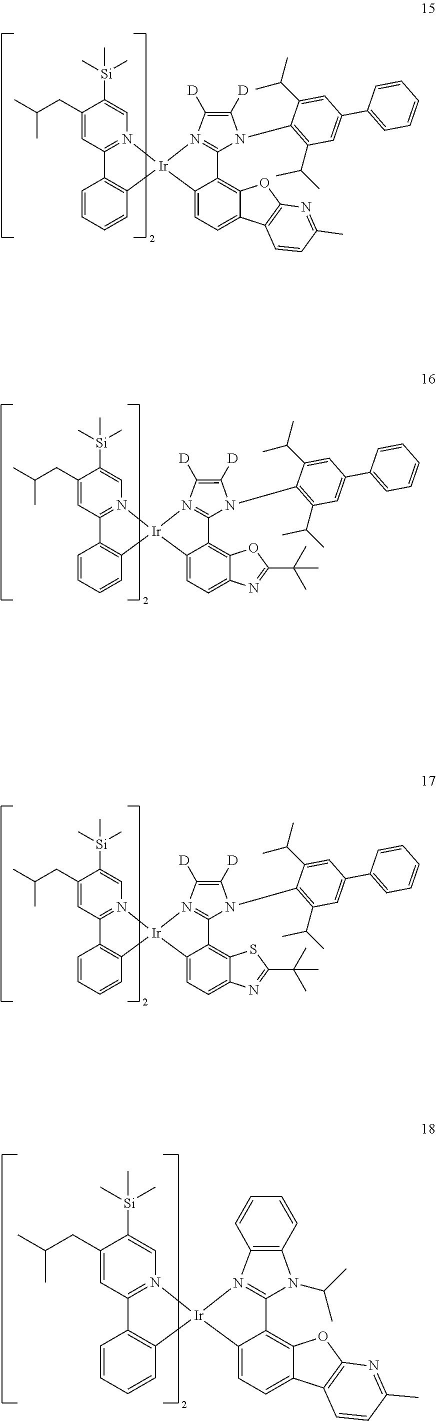

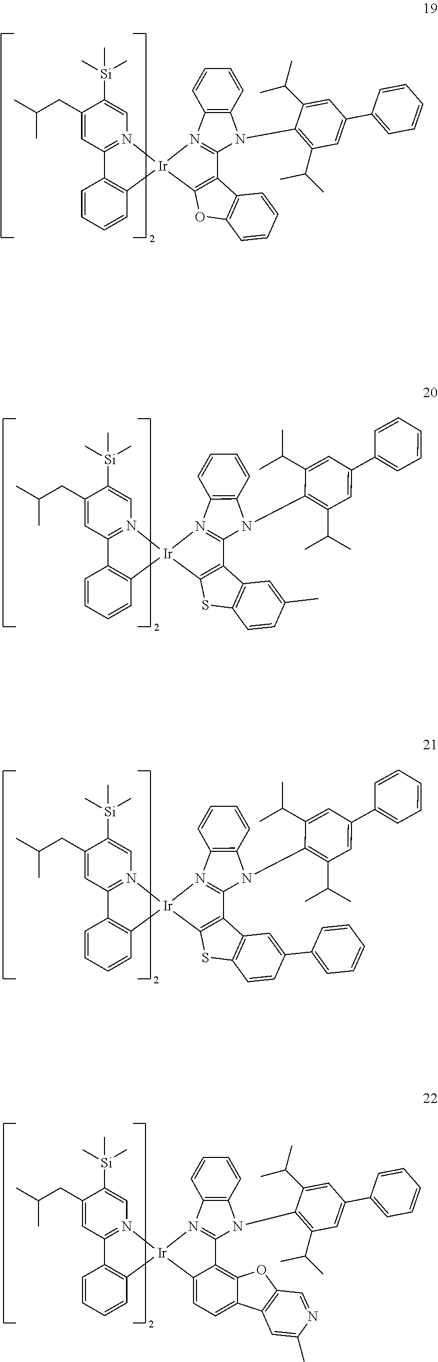

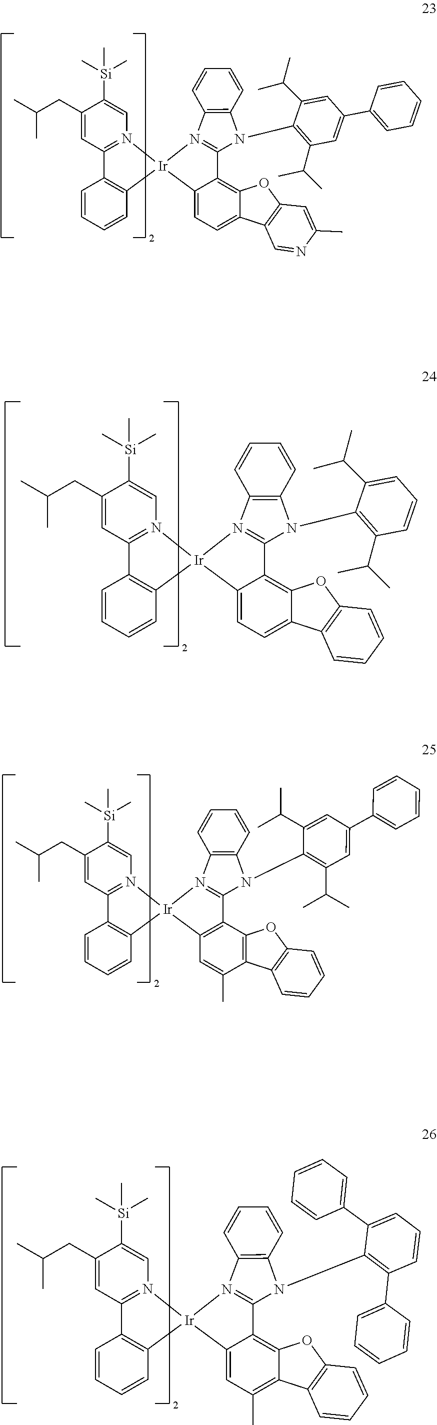

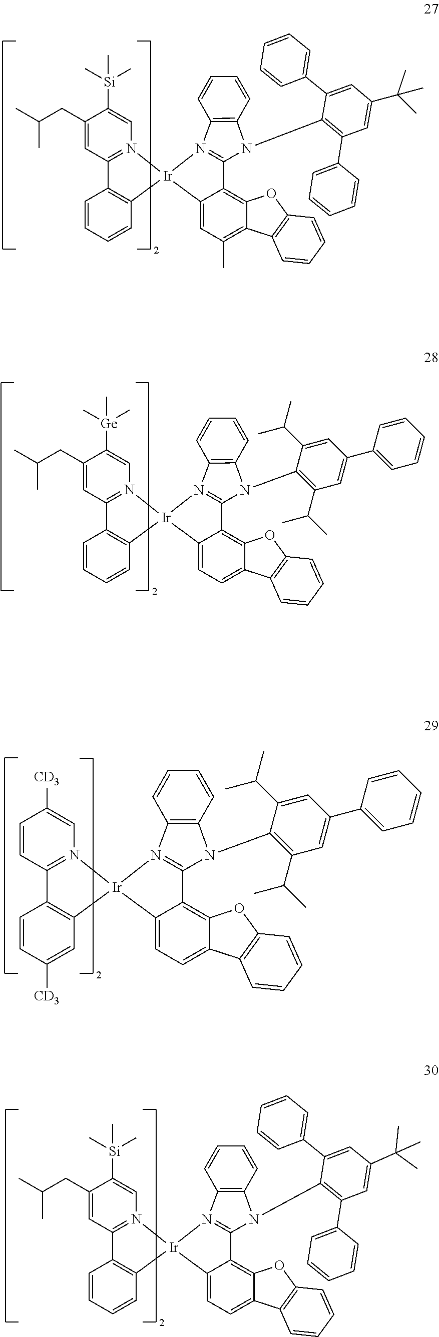

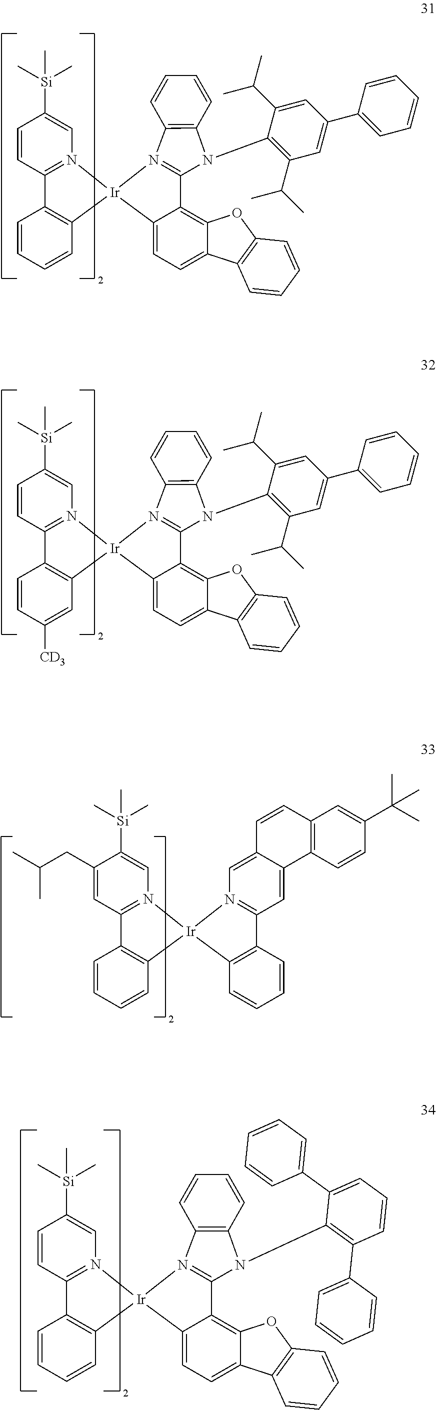

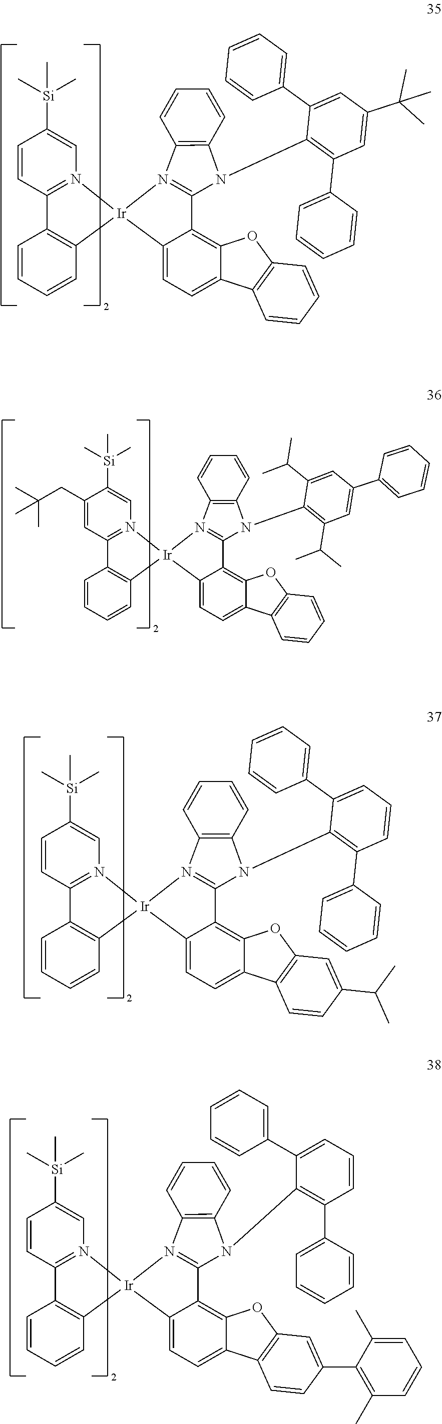

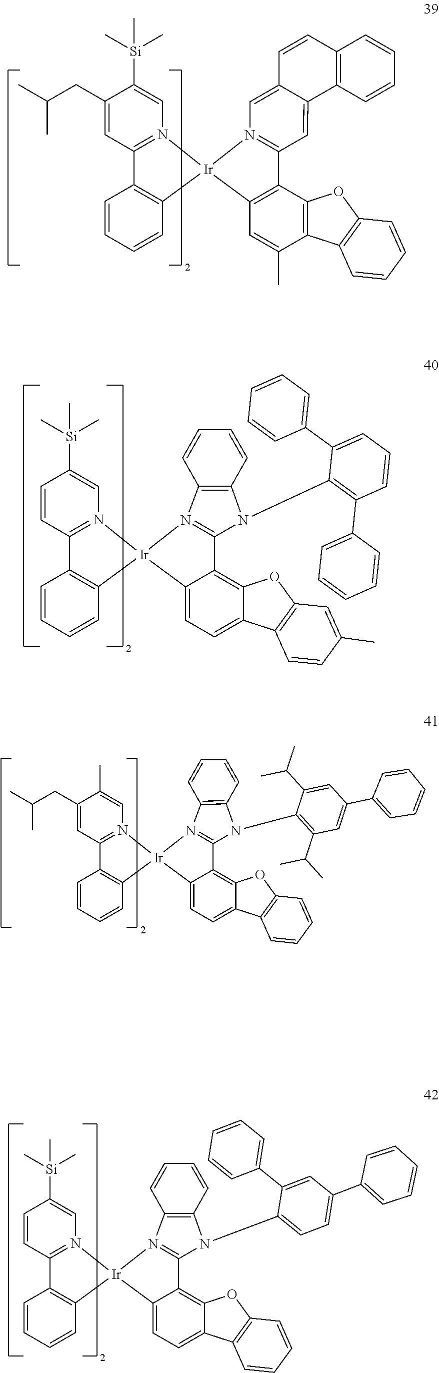

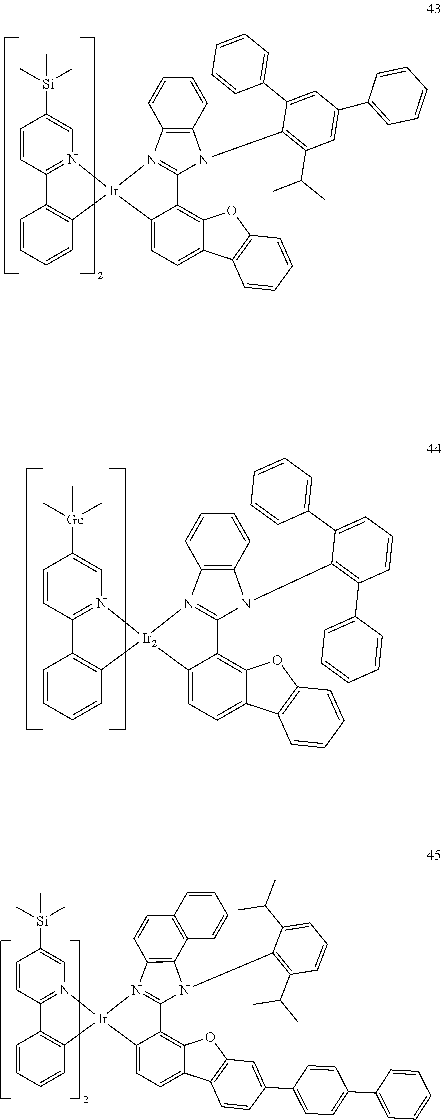

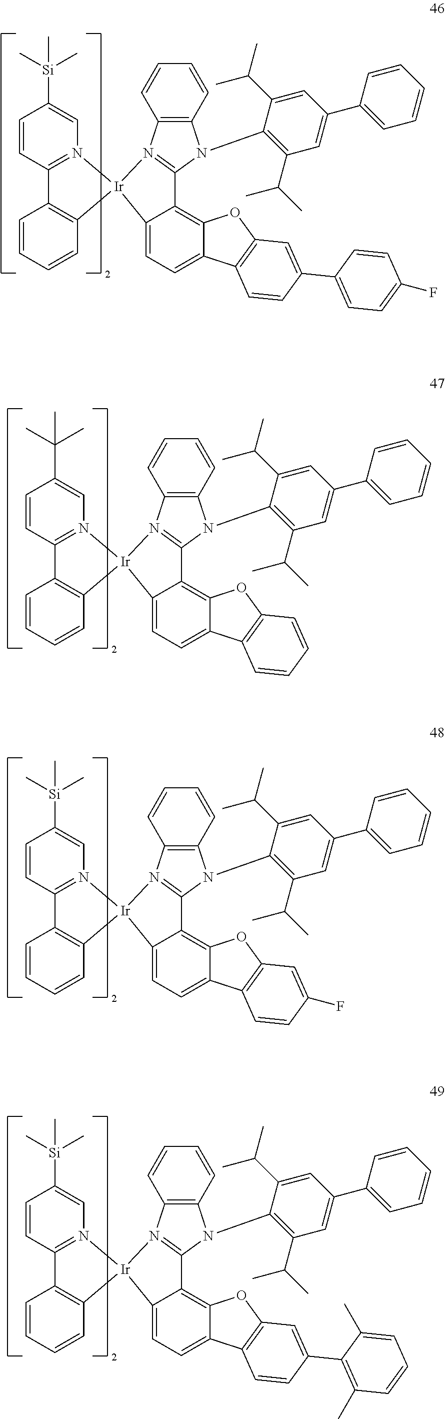

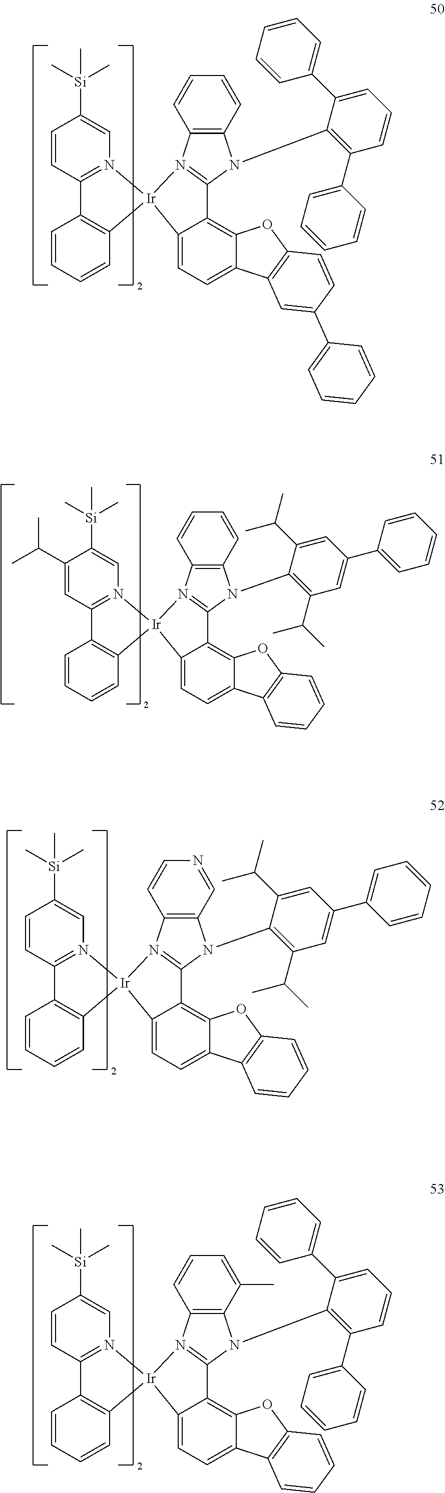

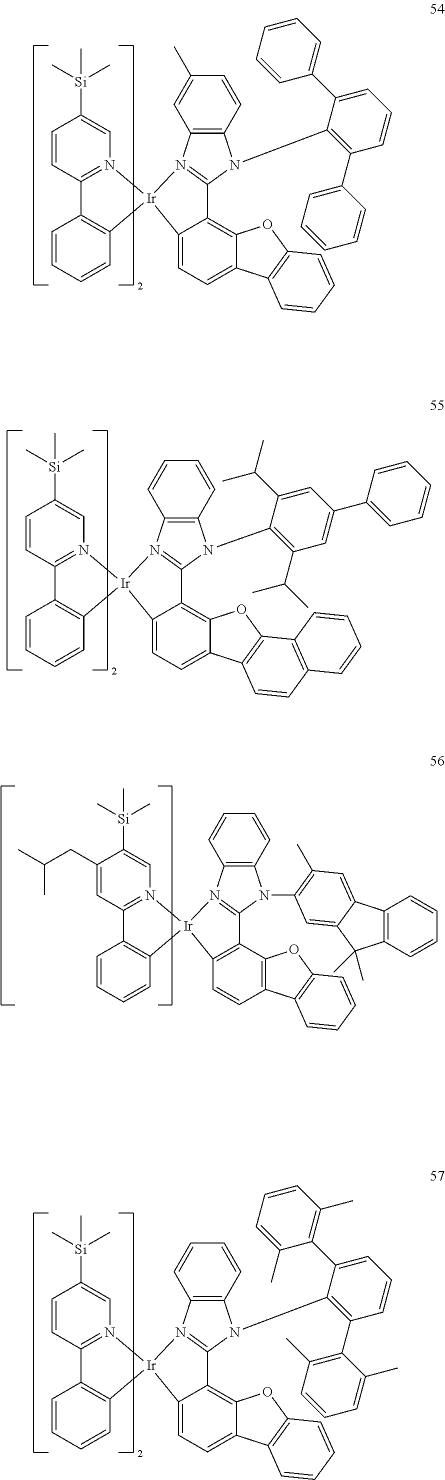

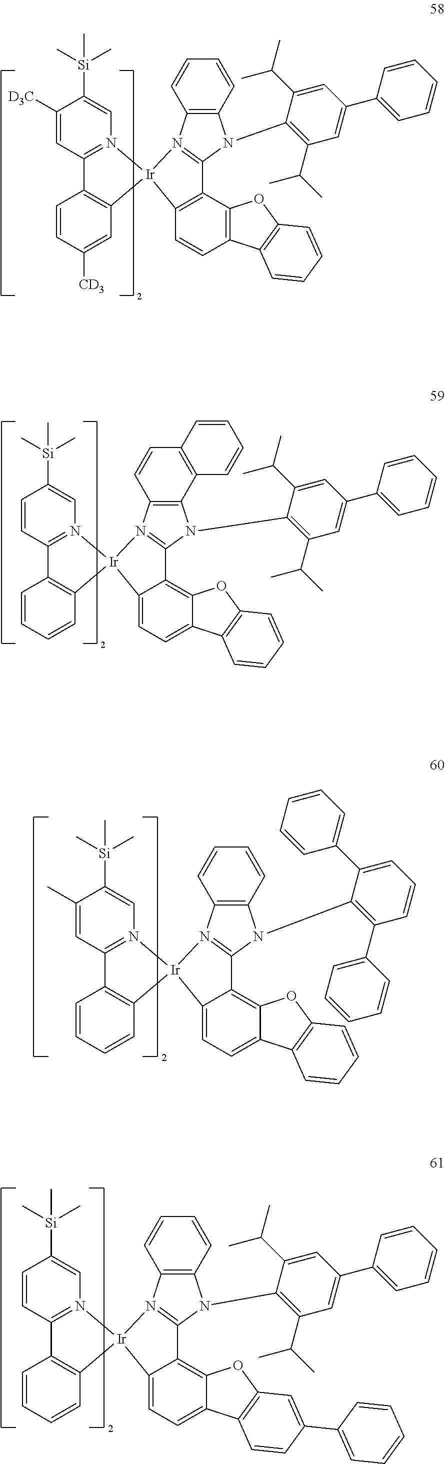

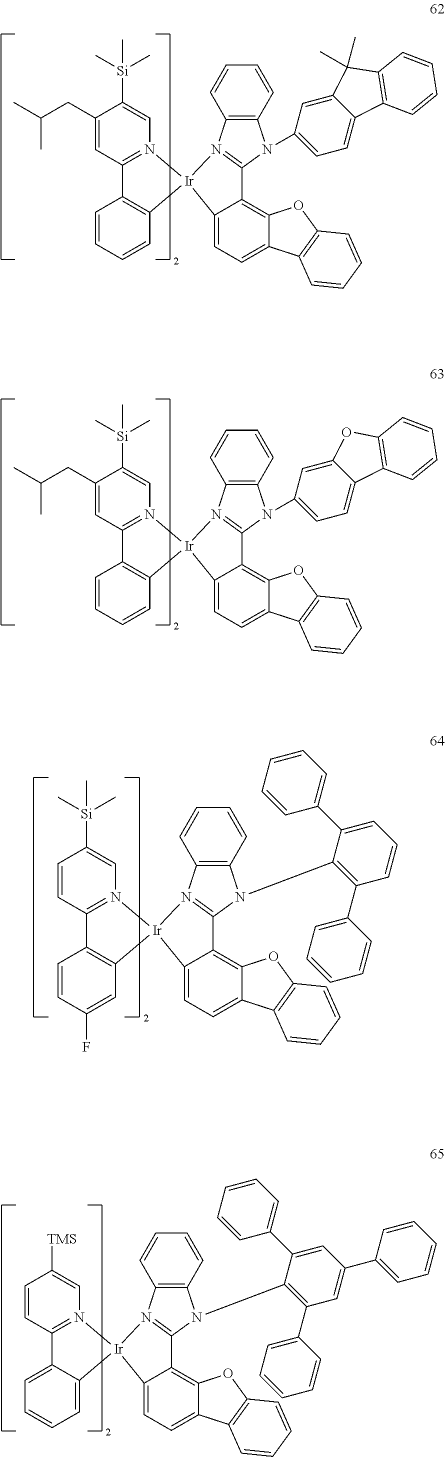

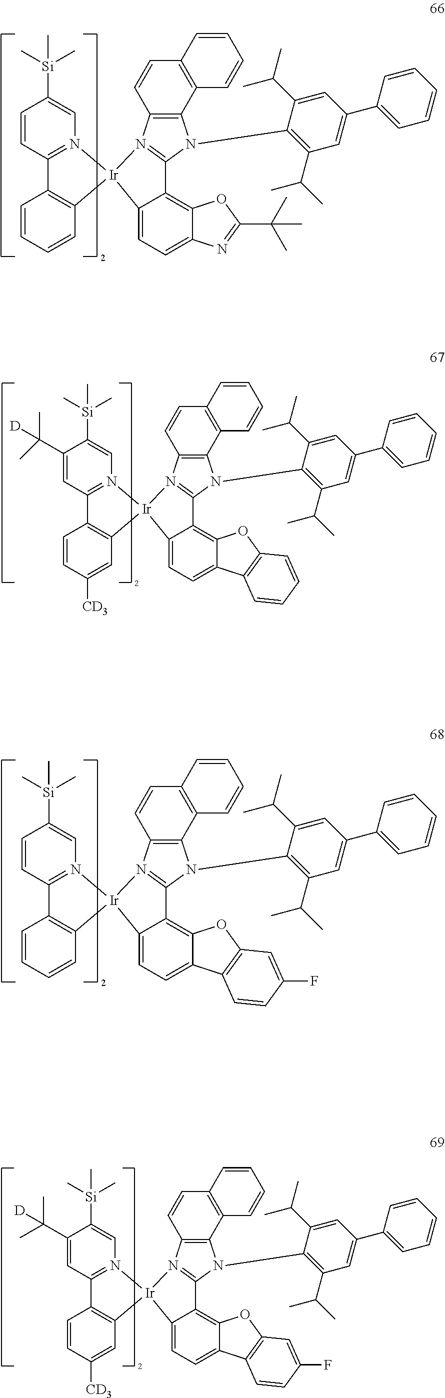

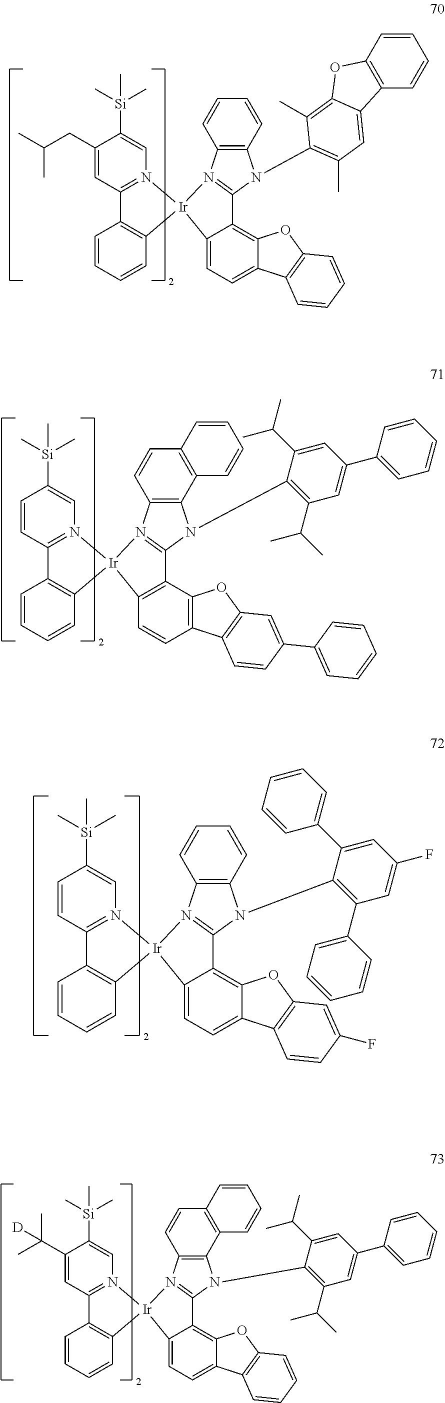

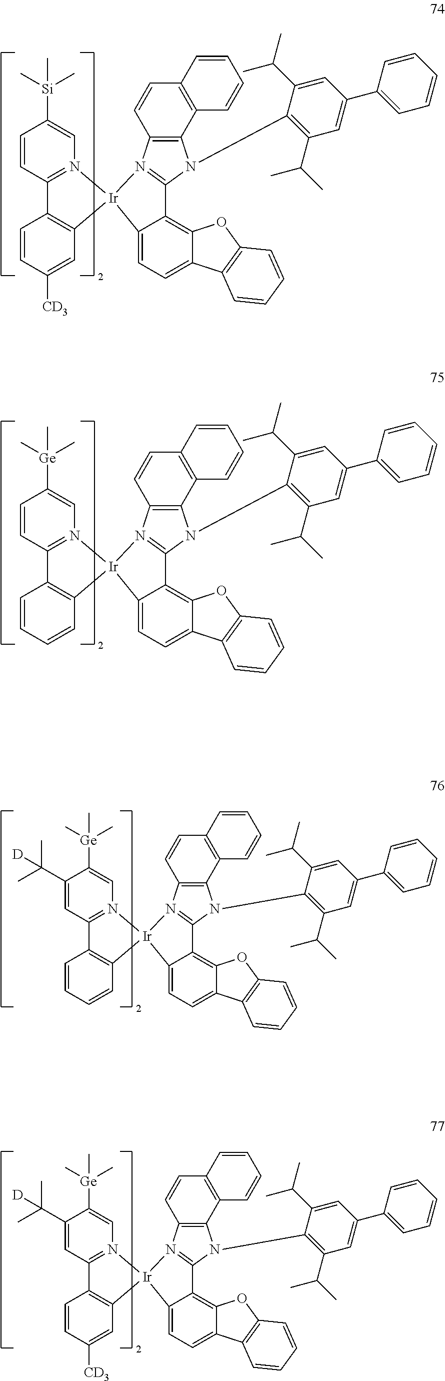

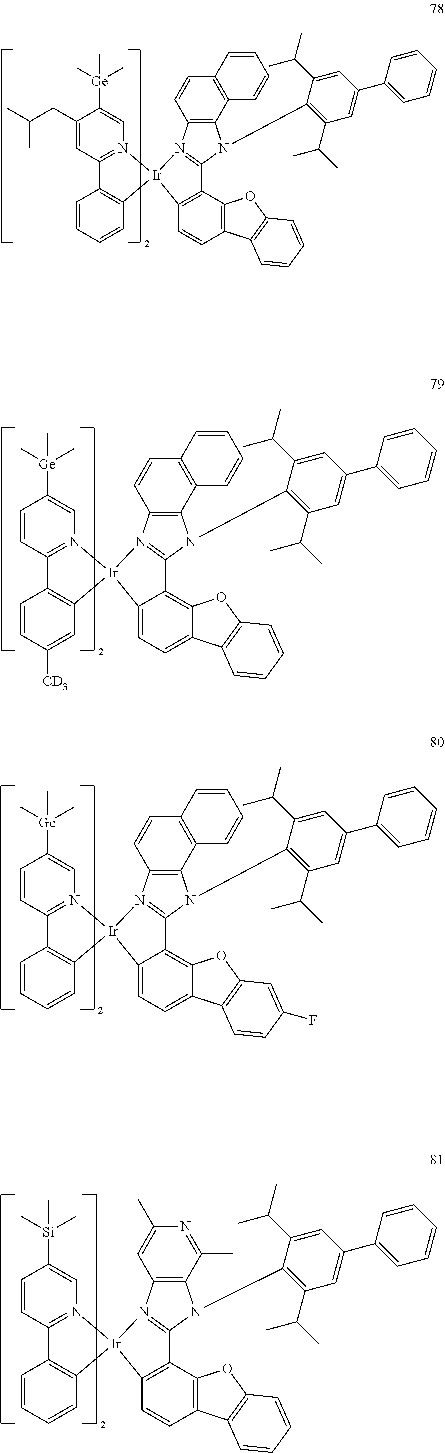

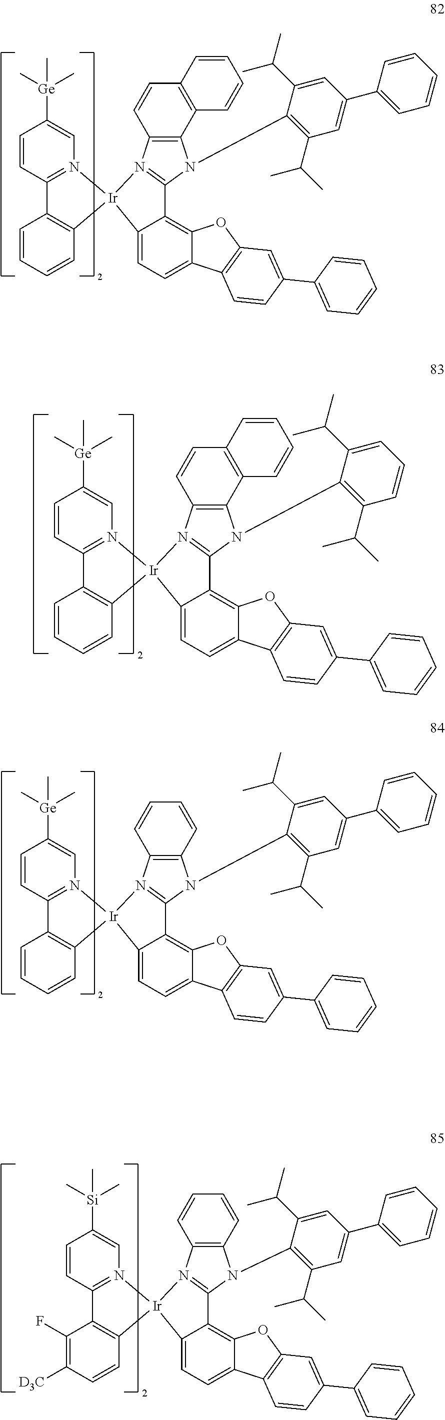

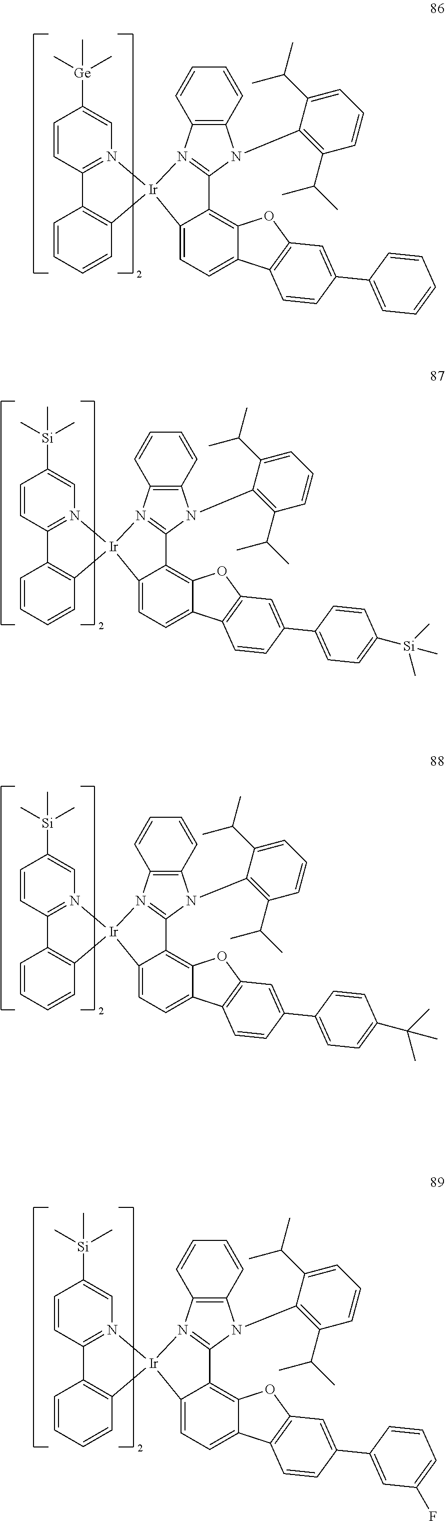

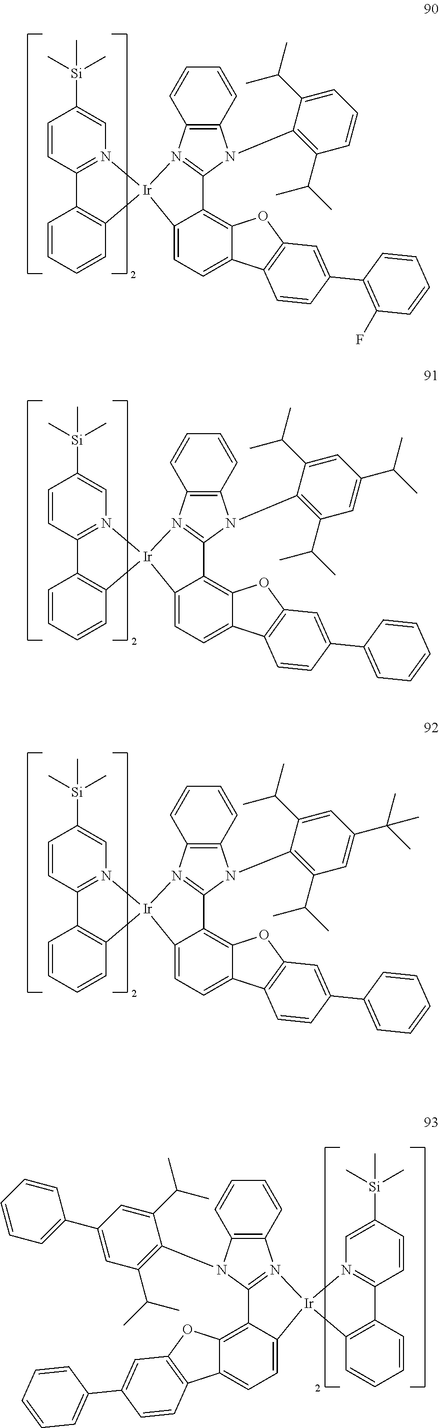

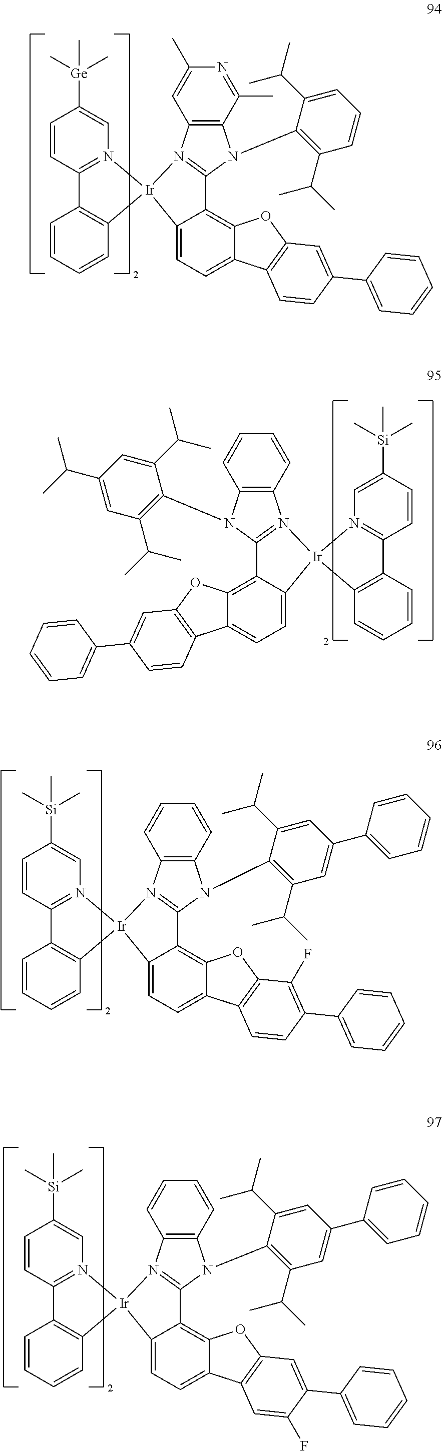

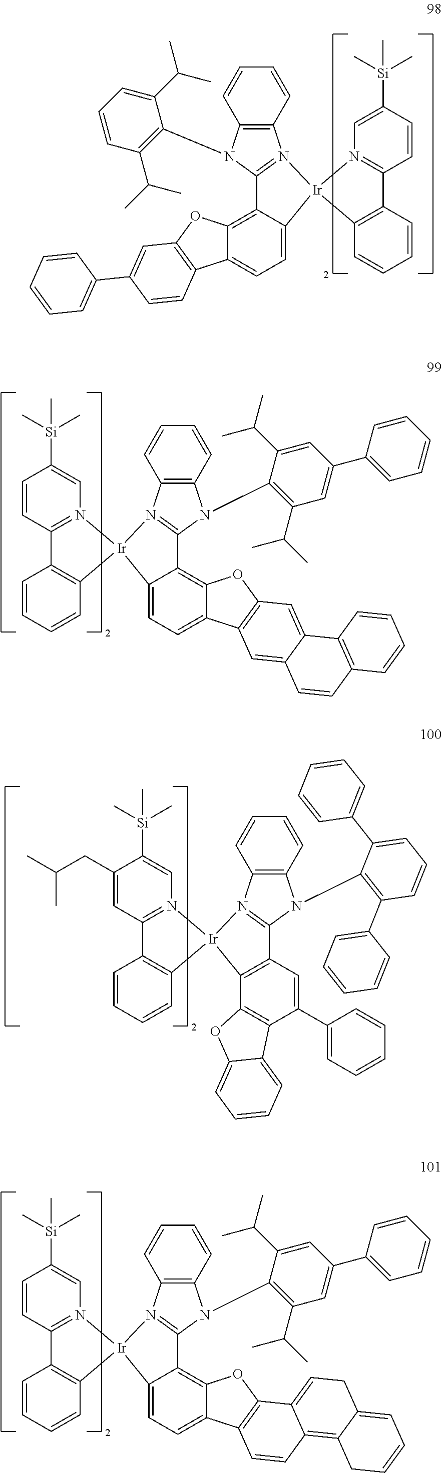

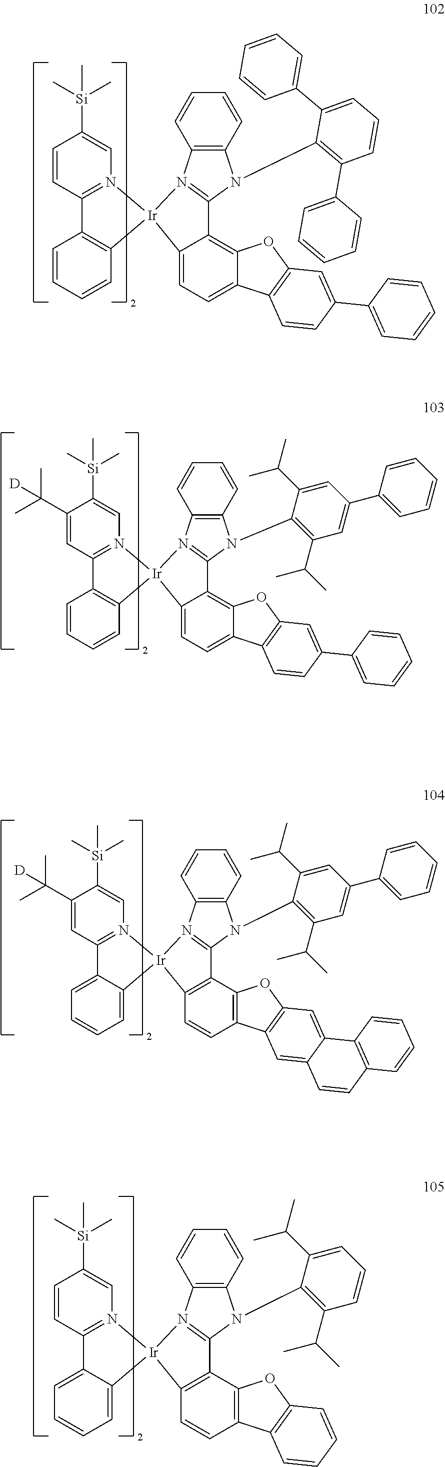

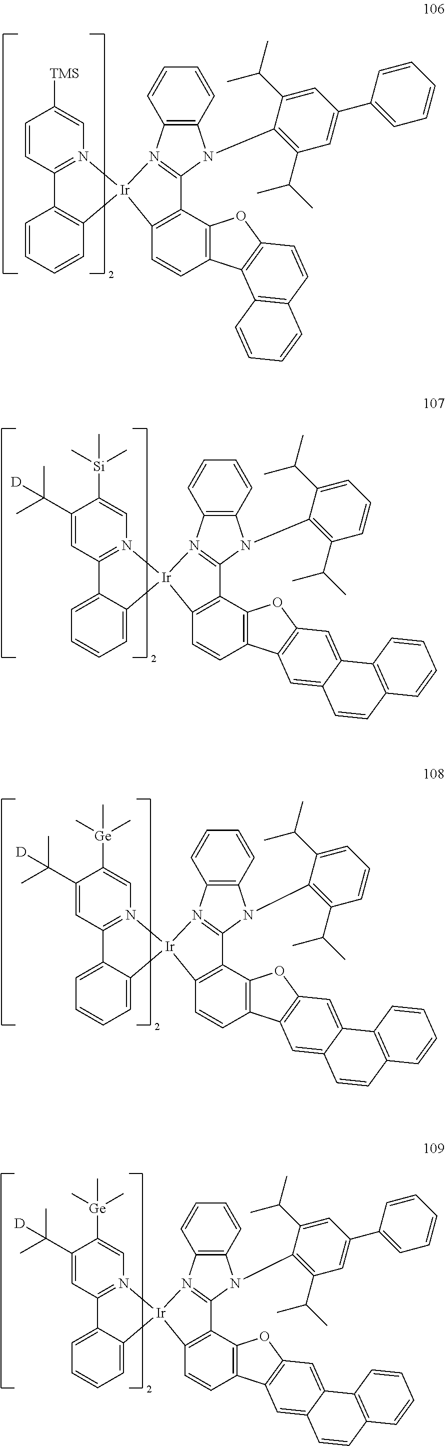

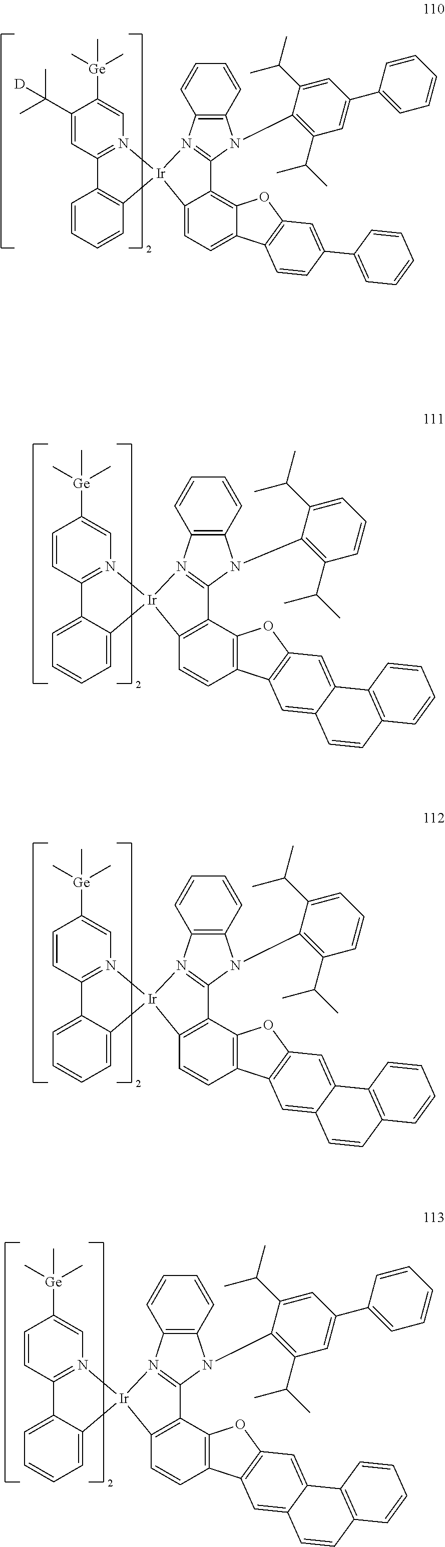

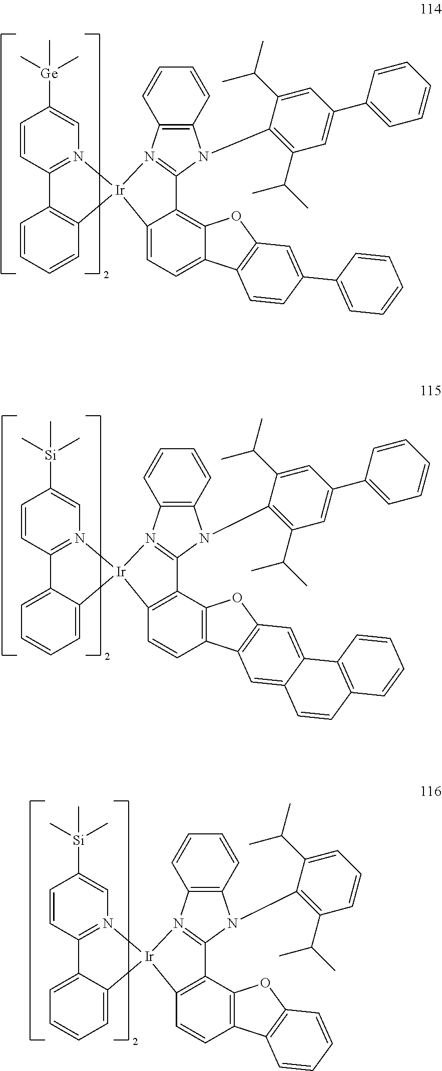

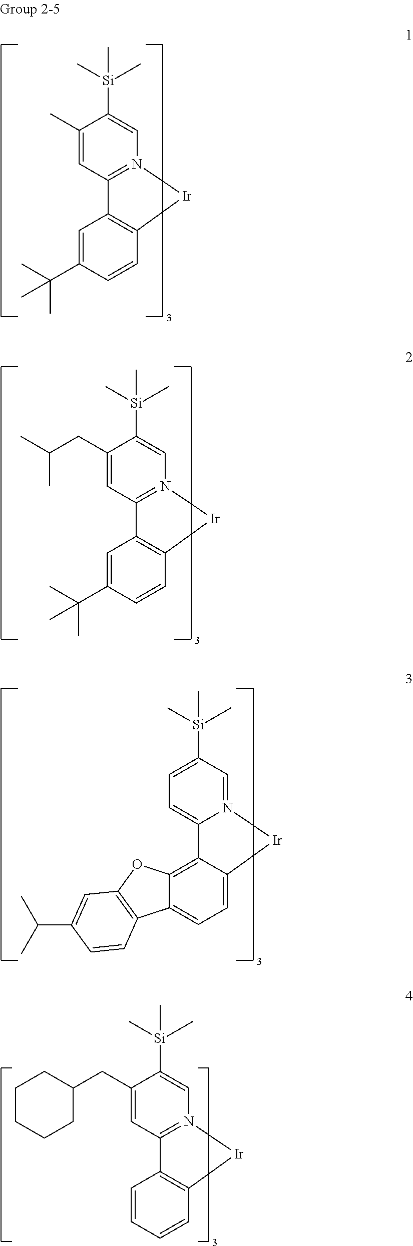

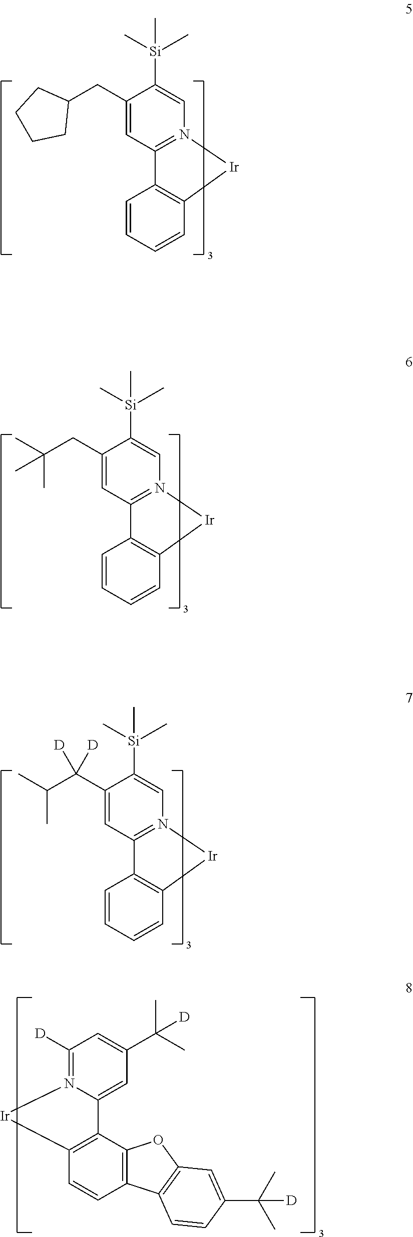

As used herein, “OMe” is a methoxy group, “TMS” is a trimethylsilyl group, and “TMG” is a trimethylgermyl group.

The composition including the first compound and the second compound as described herein may emit light having excellent luminescence efficiency and a long lifespan (for example, light having an emission peak wavelength of about 480 nm to about 580 nm or about 510 nm to about 570 nm, for example, green light, yellowish-green light, or yellow light). Accordingly, a layer including the composition, a light-emitting device including the composition, and an electronic device including the light-emitting device may be provided.

Another aspect provides a layer including the composition including the first compound and the second compound.

In one or more embodiments, the layer may emit light having an emission peak wavelength of at about 480 nm to about 580 nm, for example, about 510 nm to about 570 nm.

In one or more embodiments, the layer may emit green light, yellowish-green light, or yellow light.

In one or more embodiments, the layer may emit light having an emission peak wavelength of about 510 nm to about 540 nm.

In one or more embodiments, the layer may emit light having an emission peak wavelength of about 540 nm to about 570 nm.

In one or more embodiments, a weight ratio of the first compound and the second compound included in the layer may be about 90:10 to about 10:90, about 80:20 to about 20:80, about 70:30 to about 30:70, or about 60:40 to about 40:60.

In one or more embodiments, the weight ratio of the first compound and the second compound included in the layer may be about 50:50, that is, 1:1.

In one or more embodiments, the layer may be formed by i) co-depositing the first compound and the second compound, or ii) using a first mixture including the first compound and the second compound.

In one or more embodiments, the layer may include a host and a dopant, wherein the host does not include a transition metal, and the dopant may include the composition including the first compound and the second compound. In one or more embodiments, the layer may be formed by i) co-depositing the host and the dopant, or ii) using a second mixture including the host and the dopant.

In the layer, an amount of the host may be greater than that of the dopant.

For example, a weight ratio of the host and the dopant in the layer may be about 99:1 to about 55:45, about 97:3 to about 60:40, or about 95:5 to about 70:30.

The host in the layer may include a hole-transporting compound, an electron-transporting compound, a bipolar compound, or a combination thereof.

Another aspect provides a light-emitting device including a first electrode; a second electrode; and an organic layer arranged between the first electrode and the second electrode, wherein the organic layer includes an emission layer, and wherein the organic layer includes the composition including the first compound and the second compound.

The light-emitting device may have excellent driving voltage, excellent external quantum efficiency, and excellent lifetime characteristics by including the composition including the first compound and the second compound as described above.

In one or more embodiments, the emission layer included in the organic layer of the light-emitting device may include the composition including the first compound and the second compound.

In one or more embodiments, the emission layer may include a host and a dopant, wherein the host may not include a transition metal, and the dopant may include the composition described herein.

The host included in the emission layer may include a hole-transporting compound, an electron-transporting compound, a bipolar compound, or a combination thereof.

For example, the host may include a hole-transporting compound and an electron-transporting compound, wherein the hole-transporting compound and the electron-transporting compound may be different from each other.

The emission layer may be formed by i) co-depositing the host and the dopant, or ii) using a second mixture including the host and the dopant.

The emission layer may emit a third light having a third spectrum, and λP(EML) is an emission peak wavelength (nm) of the third spectrum. For example, the λP(EML) may be evaluated from an electroluminescence spectrum of the light-emitting device.

The light-emitting device may emit a fourth light having a fourth spectrum and extracted to the outside of the light-emitting device through the first electrode and/or the second electrode of the light-emitting device, and λP(OLED) is an emission peak wavelength (nm) of the fourth spectrum. For example, the λP(OLED) may be evaluated from an electroluminescence spectrum of the light-emitting device.

For example, the λP(EML) and the λP(OLED) may each independently be about 480 nm to about 580 nm, for example, about 510 nm to about 570 nm.

In one or more embodiments, the λP(EML) and the λP(OLED) may each independently be about 510 nm to about 540 nm.

In one or more embodiments, the λP(EML) and the λP(OLED) may each independently be about 540 nm to about 570 nm.

In one or more embodiments, each of the third light and the fourth light may be green light, yellowish-green light or yellow light.

In one or more embodiments, each of the third light and the fourth light may not be white light.

In one or more embodiments, regarding the third spectrum, i) a main emission peak having the λP(EML) may be included; but ii) an additional emission peak having an emission peak wavelength of (λP(EML)+50 nm) or greater, or (λP(EML)-50 nm) or less may not be included.

In one or more embodiments, regarding the third spectrum, i) a main emission peak having the λP(EML) may be included; but ii) an additional emission peak having an emission peak wavelength in a red light region and/or a blue light region may not be included.

In one or more embodiments, regarding the fourth spectrum, i) a main emission peak having the λP(OLED) may be included; but ii) an additional emission peak having an emission peak wavelength of (λP(OLED)+50 nm) or greater, or (λP(OLED)-50 nm) or less may not be included.

In one or more embodiments, regarding the fourth spectrum, i) a main emission peak having the λP(EML) may be included; but ii) an additional emission peak having an emission peak wavelength in a red light region and/or a blue light region may not be included.

In one or more embodiments, in the emission layer,

an absolute value of a difference between λP(Pt) and λP(Ir) may be 0 nm to about 30 nm,

an absolute value of difference between λP(EML) and λP(Pt) (or an absolute value of the difference between λP(OLED) and λP(Pt)) may be 0 nm to about 30 nm, and

an absolute value of the difference between λP(EML) and λP(Ir) (or an absolute value of the difference between λP(OLED) and λP(Ir) may be 0 nm to about 30 nm.

In one or more embodiments,

the absolute value of the difference between λP(Pt) and λP(Ir) may be 0 nm to about 10 nm,

the absolute value of the difference between λP(EML) and λP(Pt) (or the absolute value of the difference between λP(OLED) and λP(Pt)) may be 0 nm to about 10 nm, and

the absolute value of the difference between λP(EML) and λP(Ir) (or the absolute value of the difference between λP(OLED) and λP(Ir)) may be 0 nm to about 10 nm.

In one or more embodiments, in the emission layer,

λP(Pt)=λP(Ir)=λP(EML),

λP(Pt)≤λP(Ir)<λP(EML),

λP(Pt)<λP(Ir)≤λP(EML),

λP(Ir)≤λP(Pt)<λP(EML), or

λP(Ir)<λP(Pt)≤λP(EML).

In one or more embodiments, in the light-emitting device,

λP(Pt)=λP(Ir)=λP(OLED),

λP(Pt)≤λP(Ir)<λP(OLED),

λP(Pt)<λP(Ir)≤λP(OLED),

λP(Ir)≤λP(Pt)<λP(OLED), or

λP(Ir)<λP(Pt)≤λP(OLED).

Details on λP(Pt), λP(Ir), λP(EML), and λP(OLED) may be as described herein.

The first electrode may be an anode, which is a hole injection electrode, and the second electrode may be a cathode, which is an electron injection electrode; or the first electrode may be a cathode, which is an electron injection electrode, and the second electrode may be an anode, which is a hole injection electrode.

For example, in the light-emitting device, the first electrode may be an anode, and the second electrode may be a cathode, and the organic layer may further include a hole transport region arranged between the first electrode and the emission layer, and an electron transport region arranged between the emission layer and the second electrode, wherein the hole transport region may include a hole injection layer, a hole transport layer, an electron blocking layer, a buffer layer, or a combination thereof, and the electron transport region may include a hole blocking layer, an electron transport layer, an electron injection layer, or a combination thereof.

The term “organic layer” as used herein refers to a single layer and/or a plurality of layers arranged between the first electrode and the second electrode of the light-emitting device. The “organic layer” may include, in addition to an organic compound, an organometallic complex including a metal.

The FIGURE is a schematic cross-sectional view of a light-emitting device 10 according to one or more embodiments. Hereinafter, a structure and a manufacturing method of a light-emitting device according to one or more embodiments will be described in further detail in connection with the FIGURE. The light-emitting device 10 includes a first electrode 11, an organic layer 15, and a second electrode 19, which are sequentially stacked.

A substrate may be additionally arranged under the first electrode 11 or above the second electrode 19. For use as the substrate, any substrate that is used in light-emitting devices of the related art may be used, and the substrate may be a glass substrate or a transparent plastic substrate, each having excellent mechanical strength, thermal stability, transparency, surface smoothness, ease of handling, and/or water resistance.

The first electrode 11 may be, for example, formed by depositing or sputtering a material for forming the first electrode 11 on the substrate. The first electrode 11 may be an anode. The material for forming the first electrode 11 may include materials with a high work function to facilitate hole injection. The first electrode 11 may be a reflective electrode, a semi-transmissive electrode, or a transmissive electrode. In one or more embodiments, the material for forming the first electrode 11 may be indium tin oxide (ITO), indium zinc oxide (IZO), tin oxide (SnO₂), or zinc oxide (ZnO). In one or more embodiments, the material for forming the first electrode 11 may be metal, such as magnesium (Mg), aluminum (Al), silver (Ag), aluminum-lithium (Al—Li), calcium (Ca), magnesium-indium (Mg—In), or magnesium-silver (Mg—Ag).

The first electrode 11 may have a single-layered structure or a multi-layered structure including two or more layers. For example, the first electrode 11 may have a three-layered structure of ITO/Ag/ITO.

The organic layer 15 is arranged on the first electrode 11.

The organic layer 15 may include a hole transport region, an emission layer, and an electron transport region.

The hole transport region may be arranged between the first electrode 11 and the emission layer.

The hole transport region may include a hole injection layer, a hole transport layer, an electron blocking layer, a buffer layer, or a combination thereof.

The hole transport region may include only either a hole injection layer or a hole transport layer. The hole transport region may have a hole injection layer/hole transport layer structure, or a hole injection layer/hole transport layer/electron blocking layer structure, wherein, for each structure, constituting layers are sequentially stacked in this stated order from the first electrode 11.

When the hole-transporting region includes a hole injection layer, the hole injection layer may be formed on the first electrode 11 by using one or more suitable methods, for example, vacuum deposition, spin coating, casting, Langmuir-Blodgett (LB) deposition, and/or inkjet printing.

When the hole injection layer is formed by vacuum deposition, the deposition conditions may vary depending on a material for forming the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 angstroms per second (Å/sec) to about 100 Å/sec.

When the hole injection layer is formed by spin coating, the coating conditions may vary depending on a material for forming the hole injection layer, and the structure and thermal characteristics of the hole injection layer. For example, the coating conditions may include a coating speed of about 2,000 revolutions per minute (rpm) to about 5,000 rpm and a heat treatment temperature of about 80° C. to about 200° C. for removing a solvent after coating.

Conditions for forming the hole transport layer and the electron blocking layer may be similar to or the same as the conditions for forming the hole injection layer.

The hole transport region may include 4,4′,4″-tris(3-methylphenylphenylamino)triphenylamine (m-MTDATA), 4,4′,4″-tris(N, N-diphenylamino)triphenylamine (TDATA), 4,4′,4″-tris{N-(2-naphthyl)-N-phenylamino}-triphenylamine (2-TNATA), N,N′-di(1-naphthyl)-N,N′-diphenylbenzidine (NPB), β-NPB, N,N′-bis(3-methylphenyl)-N,N′-diphenyl-[1,1-biphenyl]-4,4′-diamine (TPD), spiro-TPD, spiro-NPB, methylated NPB, 4,4′-cyclohexylidene bis[N,N-bis(4-methylphenyl)benzenamine] (TAPC), 4,4′-bis[N, N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201, a compound represented by Formula 202, or a combination thereof:

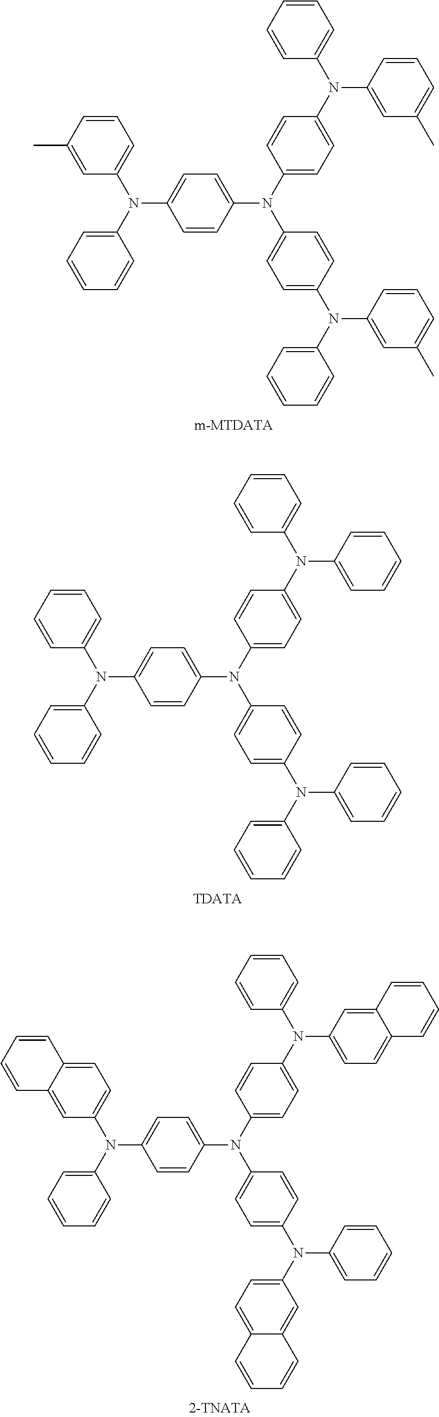

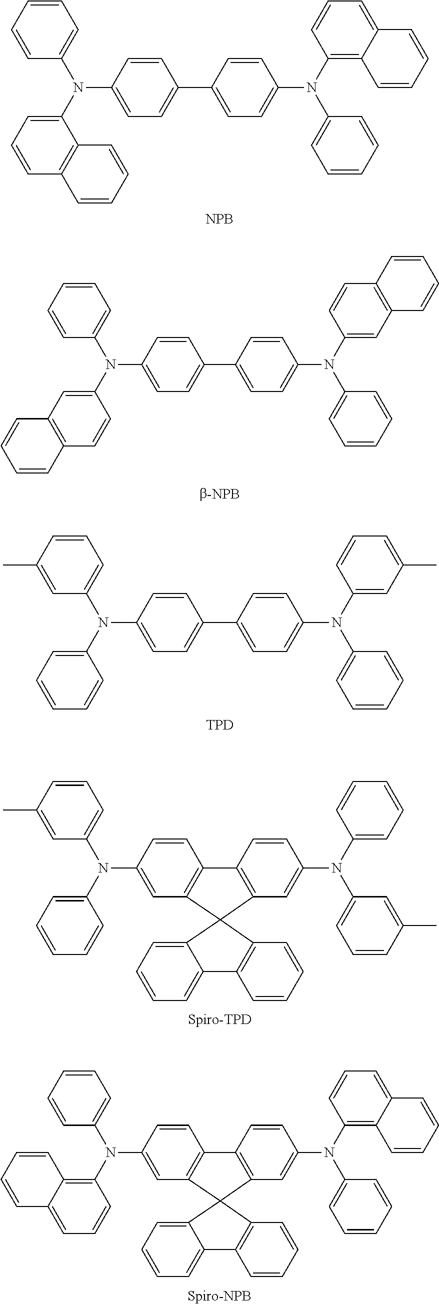

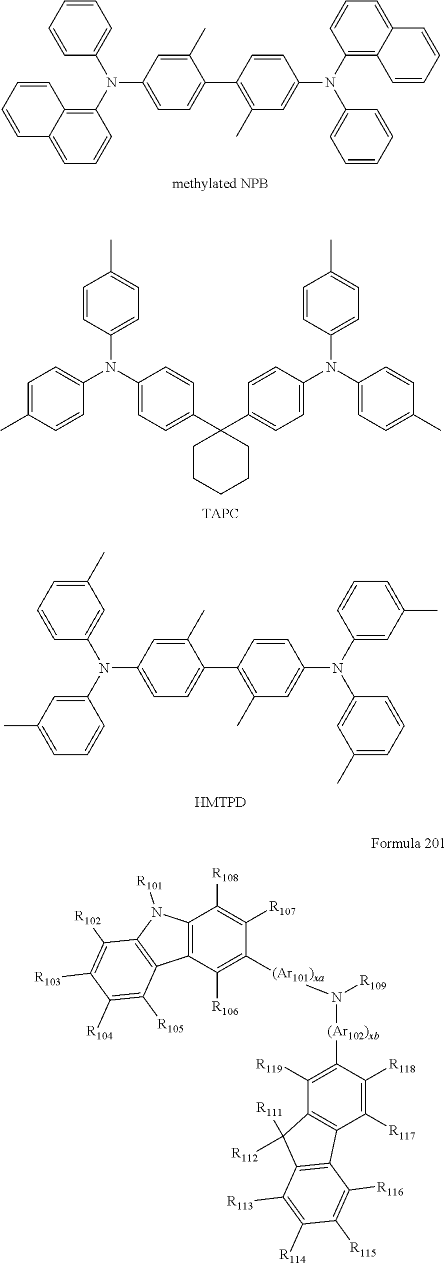

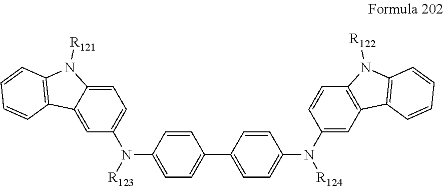

In Formula 201, Ar₁₀₁ and Ar₁₀₂ may each independently be a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each unsubstituted or substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, or a combination thereof.

In Formula 201, xa and xb may each independently be an integer from 0 to 5, or may be 0, 1, or 2. For example, in Formula 201, xa may be 1, and xb may be 0.

In Formulae 201 and 202, R₁₀₁ to R₁₀₈, R₁₁₁ to R₁₁₉, and R₁₂₁ to R₁₂₄ may each independently be:

hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, a hexyl group, or the like), a C₁-C₁₀ alkoxy group (for example, a methoxy group, an ethoxy group, a propoxy group, a butoxy group, a pentoxy group, or the like), or a C₁-C₁₀ alkylthio group;

a C₁-C₁₀ alkyl group, a C₁-C₁₀ alkoxy group, or a C₁-C₁₀ alkylthio group, each unsubstituted or substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a combination thereof; or

a phenyl group, a naphthyl group, an anthracenyl group, a fluorenyl group or a pyrenyl group, each unsubstituted or substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, a C₁-C₁₀ alkylthio group, or a combination thereof.

In Formula 201, R₁₀₉ may be a phenyl group, a naphthyl group, an anthracenyl group, or a pyridinyl group, each substituted or unsubstituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₁-C₂₀ alkylthio group, a phenyl group, a naphthyl group, an anthracenyl group, a pyridinyl group, or a combination thereof.

In one or more embodiments, the compound represented by Formula 201 may be represented by Formula 201A:

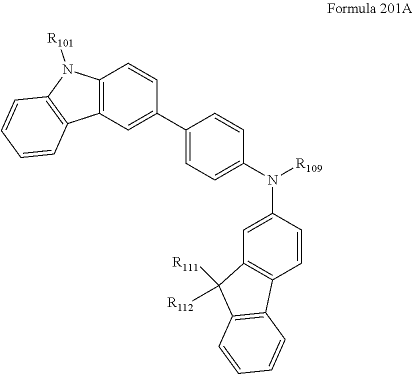

wherein, in Formula 201A, R₁₀₁, R₁₁₁, R₁₁₂, and R₁₀₉ may each be as described herein.

For example, the hole transport region may include one of Compounds HT1 to HT20, or a combination thereof:

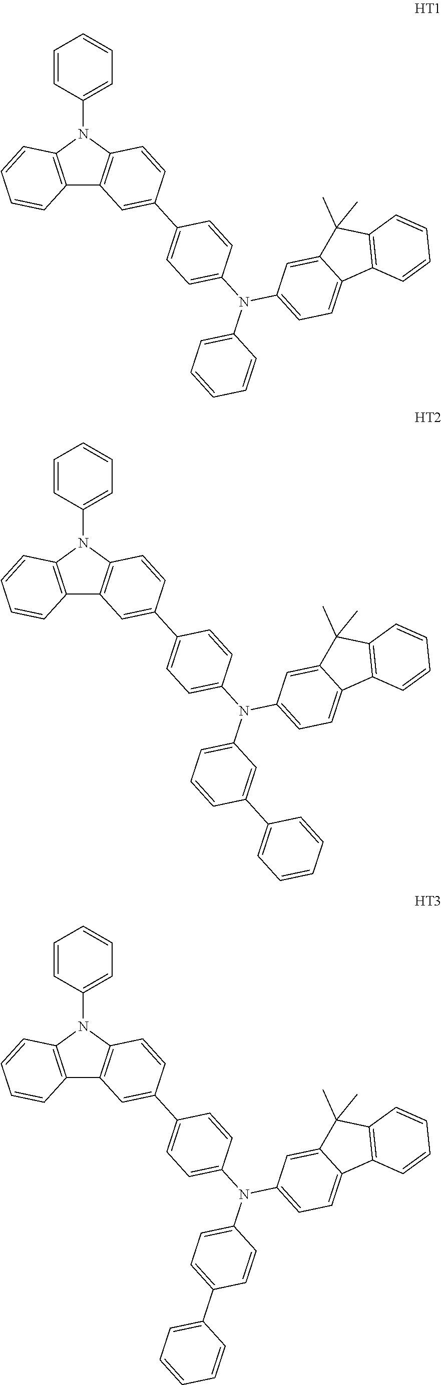 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

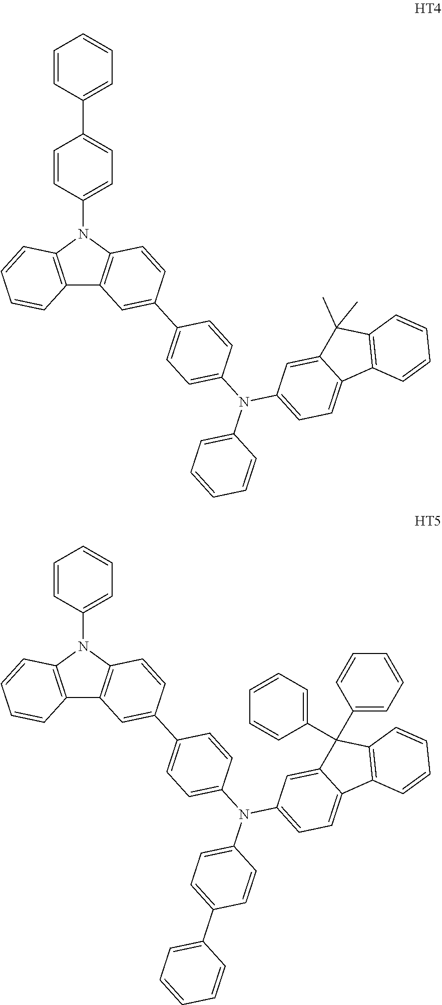 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

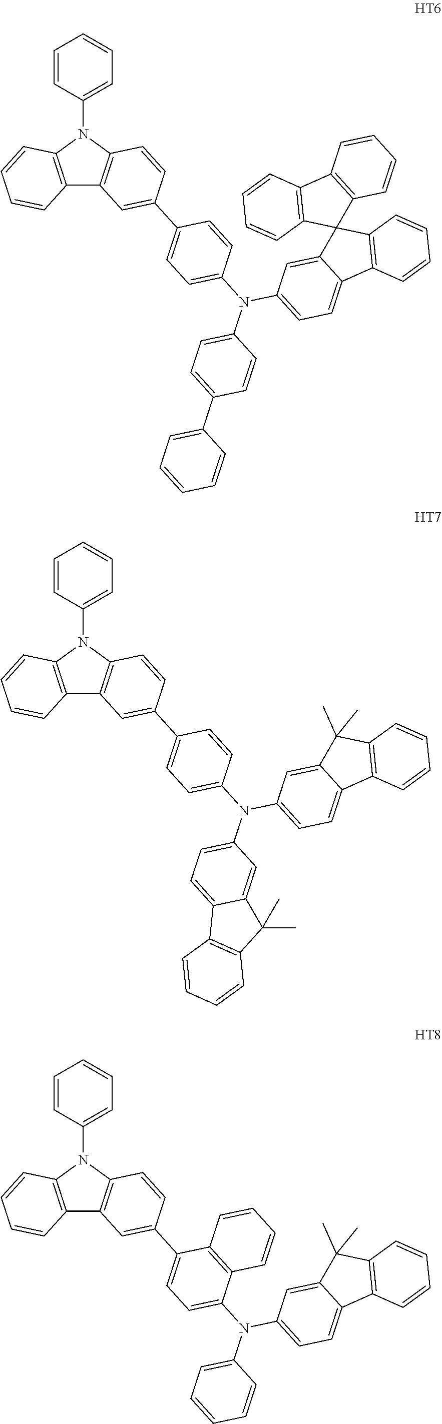 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

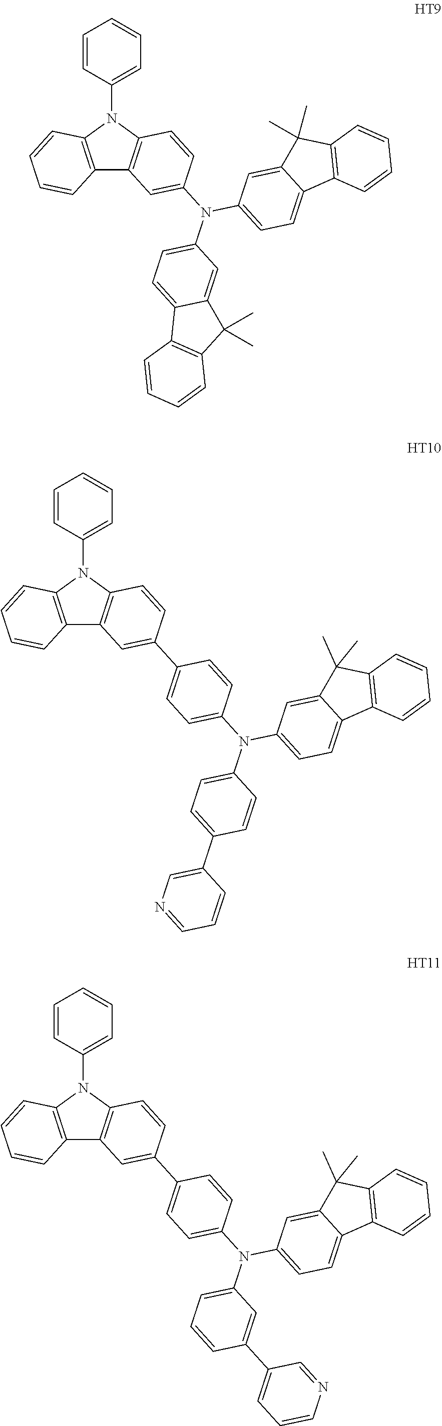 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

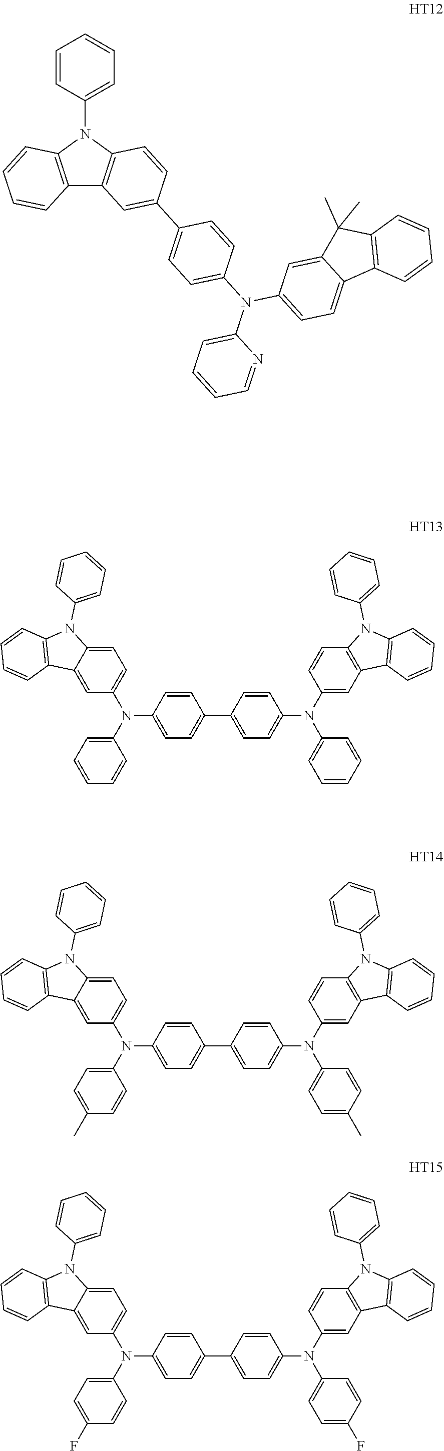 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

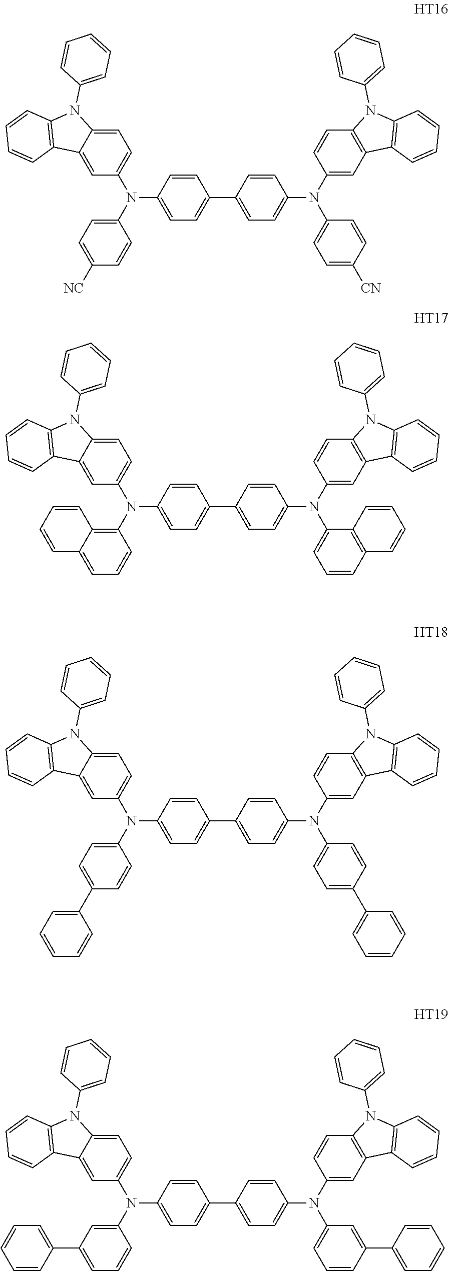 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

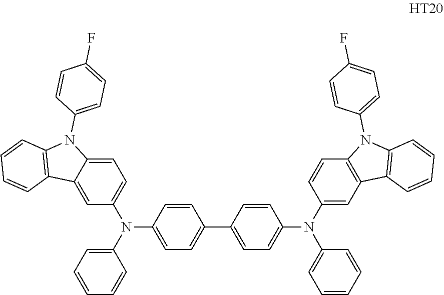 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be about 100 angstroms (Å) to about 10,000 Å, for example, about 100 Å to about 1,000 Å. When the hole transport region includes a hole injection layer, a hole transport layer, an electron blocking layer, or a combination thereof, a thickness of the hole injection layer may be about 100 Å to about 10,000 Å, for example, about 100 Å to about 1,000 Å, and a thickness of the hole transport layer may be about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be a quinone derivative, a metal oxide, a cyano group-containing compound, or a combination thereof. For example, the p-dopant may be: a quinone derivative, such as tetracyanoquinodimethane (TC N Q), 2,3,5,6-tetrafluoro-tetracyano-1,4-benzoquinonedimethane (F4-TCNQ), F6-TCNNQ, or the like; metal oxide, such as tungsten oxide, molybdenum oxide, or the like; a cyano group-containing compound, such as Compound HT-D1 or the like; or a combination thereof:

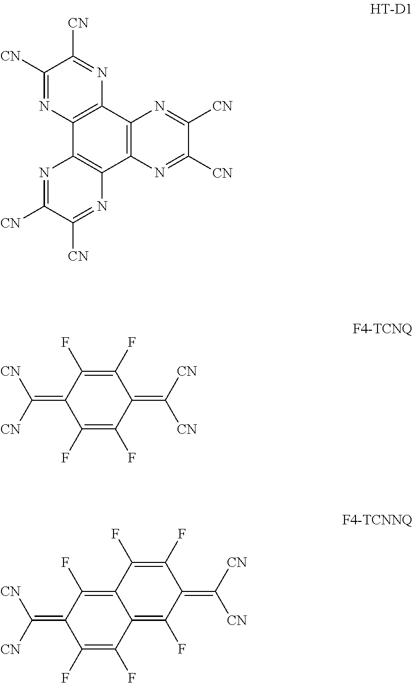

The hole transport region may further include a buffer layer.

The buffer layer may compensate for an optical resonance distance according to a wavelength of light emitted from the emission layer, and thus, efficiency of a formed light-emitting device may be improved.

Meanwhile, when the hole transport region includes an electron blocking layer, a material for forming the electron blocking layer may include a material that is used in the hole transport region as described above, a host material described below, or a combination thereof. For example, when the hole transport region includes an electron blocking layer, the material for forming the electron blocking layer may include mCP described below, Compound H-H1 described below, or a combination thereof.

Then, the emission layer 15 may be formed on the hole transport region by using methods, such as vacuum deposition, spin coating, casting, LB deposition, inkjet printing, or the like. When the emission layer is formed by vacuum deposition or spin coating, the deposition or coating conditions may be similar to those applied in forming the hole injection layer although the deposition or coating conditions may vary depending on a material that is used to form the emission layer.

In one or more embodiments, the emission layer may include the composition including the first compound and the second compound as described herein. In one or more embodiments, the emission layer may include a layer including the composition including the first compound and the second compound as described herein.

In one or more embodiments, the emission layer may include a host and a dopant, wherein the host does not include a transition metal, and the dopant includes the composition including the first compound and the second compound as described herein.

The host may include 1,3,5-tri(1-phenyl-1H-benzo[d]imidazol-2-yl)benzene (TPBi), 3-tert-butyl-9,10-di(naphth-2-yl)anthracene (TBADN), 9,10-di(naphthalen-2-yl)anthracene (ADN) (also referred to as “DNA”), 4,4′-bis(N-carbazolyl)-1,1′-biphenyl (CBP), 4,4′-bis(9-carbazolyl)-2,2′-dimethyl-biphenyl (CDBP), 1,3,5-tris(carbazole-9-yl)benzene (TCP), 1,3-bis(N-carbazolyl)benzene (mCP), Compound H50, Compound H51, Compound H52, Compound H-H1, Compound H-H2, or a combination thereof:

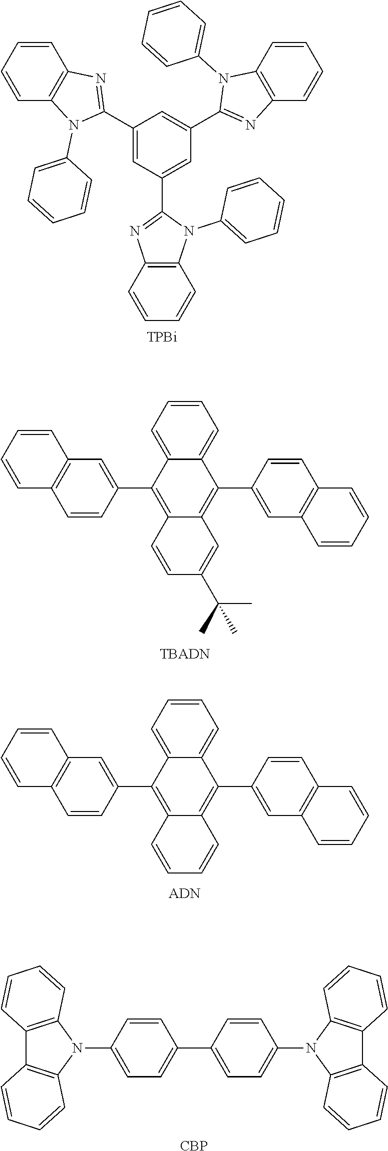

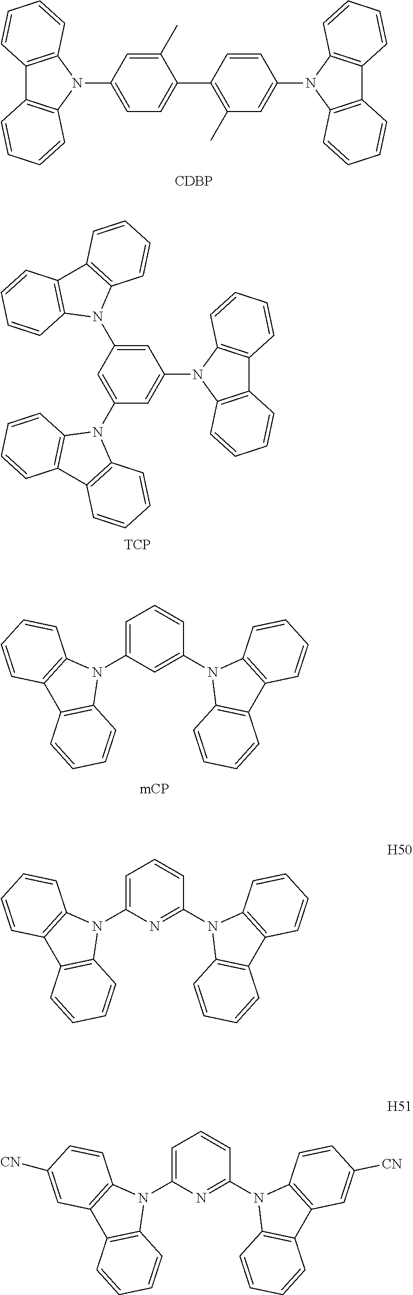

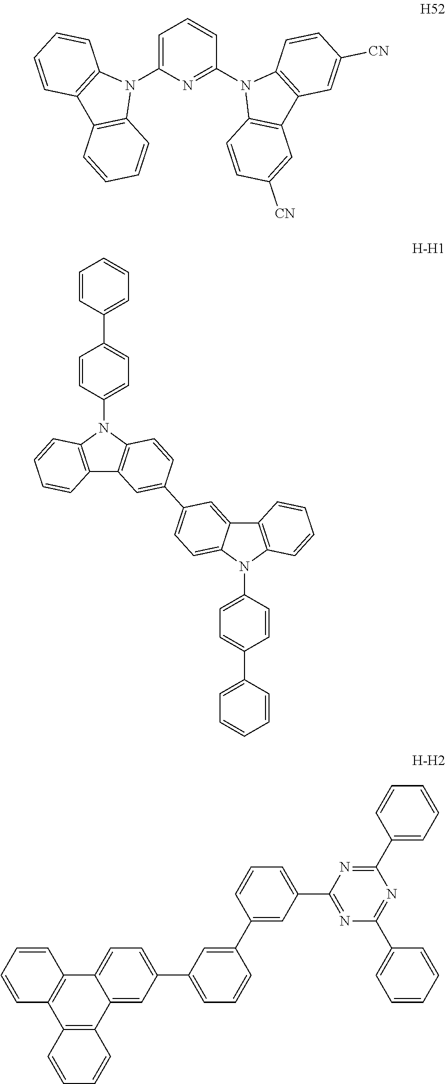 [SMILES: N#Cc1ccc2c(c1)c1cc(C#N)ccc1n2-c1cccc(-n2c3ccccc3c3ccccc32)n1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccccc3)nc(-c3cccc(-c4cccc(-c5ccc6c7ccccc7c7ccccc7c6c5)c4)c3)n2)cc1]

When the light-emitting device 10 is a full-color light-emitting device, the emission layer may be patterned into a red emission layer, a green emission layer, and/or a blue emission layer.

A thickness of the emission layer may be about 100 Å to about 1,000 Å, for example, about 200 Å to about 600 Å. When the thickness of the emission layer is within these ranges, excellent light-emission characteristics may be obtained without a substantial increase in driving voltage.

Next, the electron transport region may be arranged on the emission layer.

The electron transport region may include a hole blocking layer, an electron transport layer, an electron injection layer, or a combination thereof.

For example, the electron transport region may have a hole blocking layer/electron transport layer/electron injection layer structure or an electron transport layer/electron injection layer structure. The electron transport layer may have a single-layered structure or a multi-layered structure including two or more different materials.

Conditions for forming a hole blocking layer, an electron transport layer, and an electron injection layer which constitute the electron transport region may be understood by referring to the conditions for forming the hole injection layer.

When the electron transport region includes a hole blocking layer, the hole blocking layer may include, for example, 2,9-dimethyl-4,7-diphenyl-1,10-phenanthroline (BCP), 4,7-diphenyl-1,10-phenanthroline (Bphen), bis(2-methyl-8-quinolinolato-N1,O8)-(1,1′-biphenyl-4-olato)aluminum (BAlq), or a combination thereof:

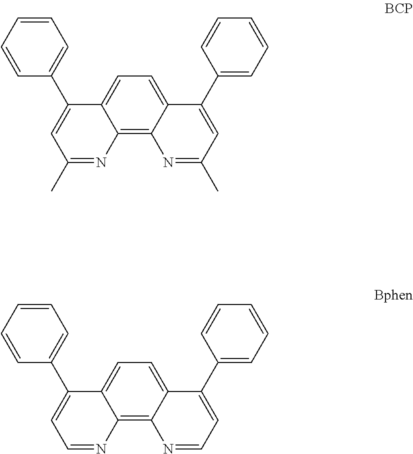 [SMILES: Cc1cc(-c2ccccc2)c2ccc3c(-c4ccccc4)cc(C)nc3c2n1 ; c1ccc(-c2ccnc3c2ccc2c(-c4ccccc4)ccnc23)cc1]

A thickness of the hole blocking layer may be about 20 Å to about 1,000 Å, for example, about 30 Å to about 600 Å. When the thickness of the hole blocking layer is within these ranges, excellent hole blocking characteristics may be obtained without a substantial increase in driving voltage.

In one or more embodiments, the electron transport layer may include BCP, Bphen, TPBi, tris(8-hydroxy-quinolinato)aluminum (Alq₃), BAlq, 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), or a combination thereof:

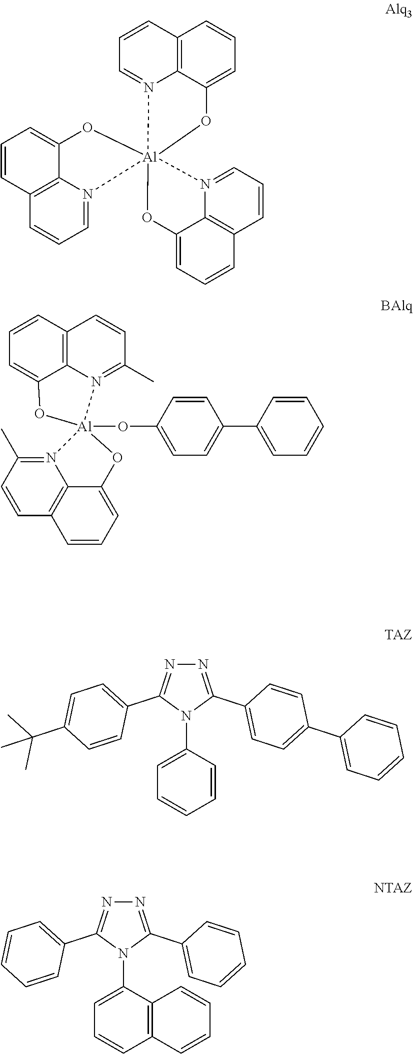

In one or more embodiments, the electron transport layer may include one of Compounds ET1 to ET25, or a combination thereof:

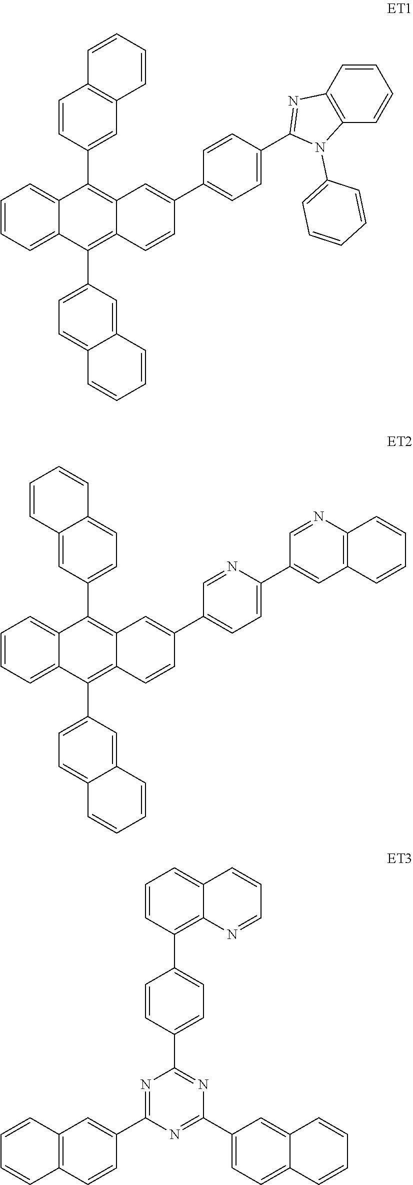 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

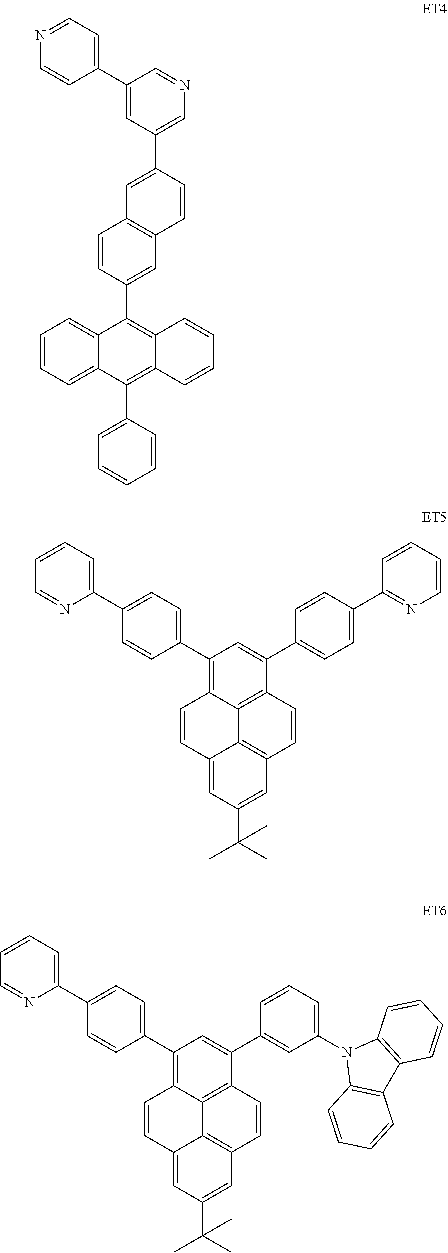 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

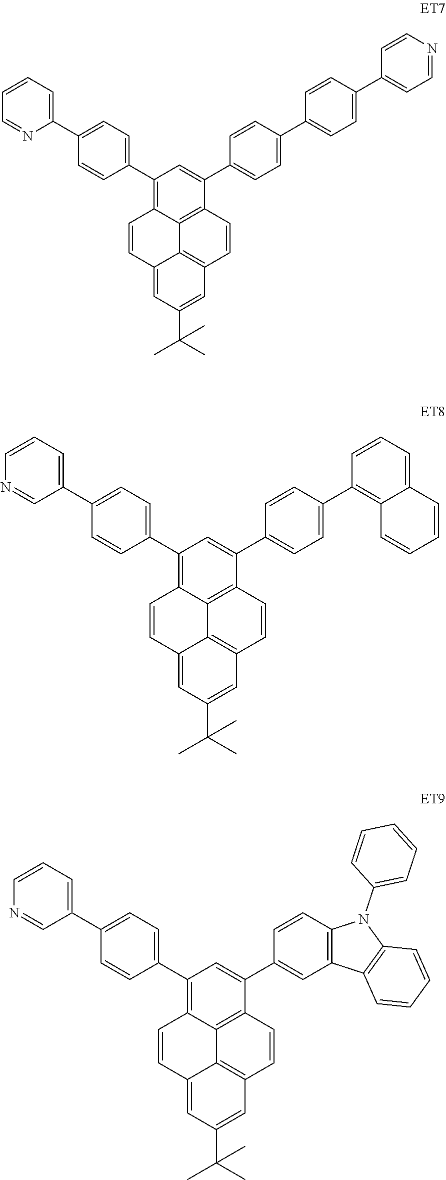 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

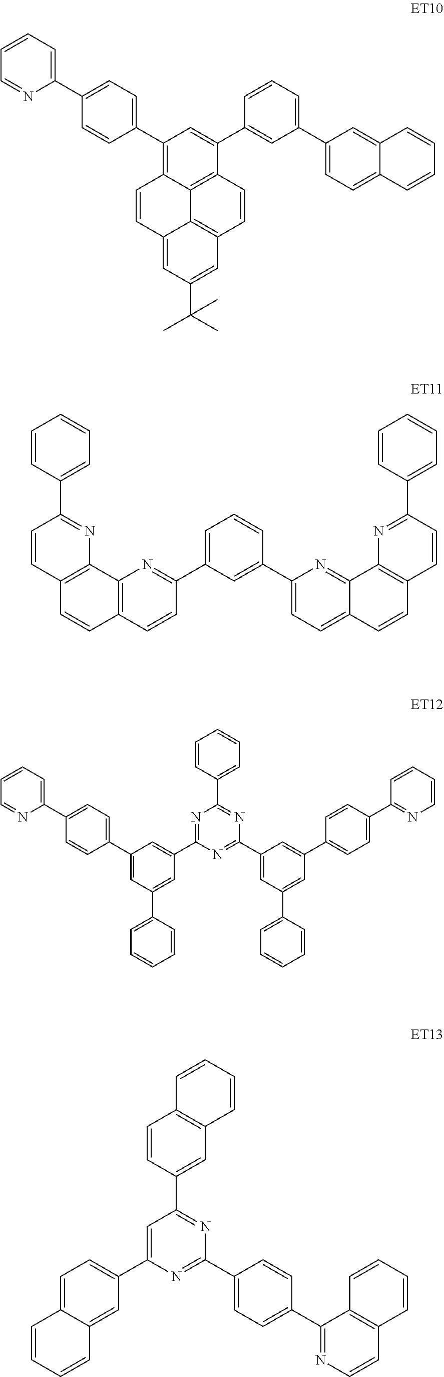 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2cc(-c3cc(-c4ccc5ccccc5c4)nc(-c4ccc(-c5nccc6ccccc56)cc4)n3)ccc2c1]

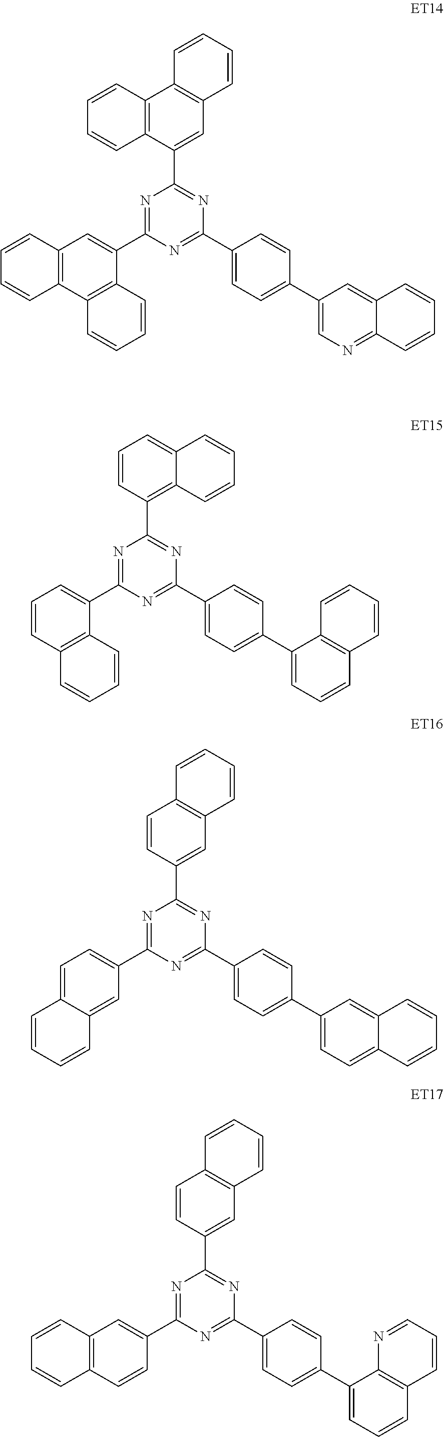 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1]

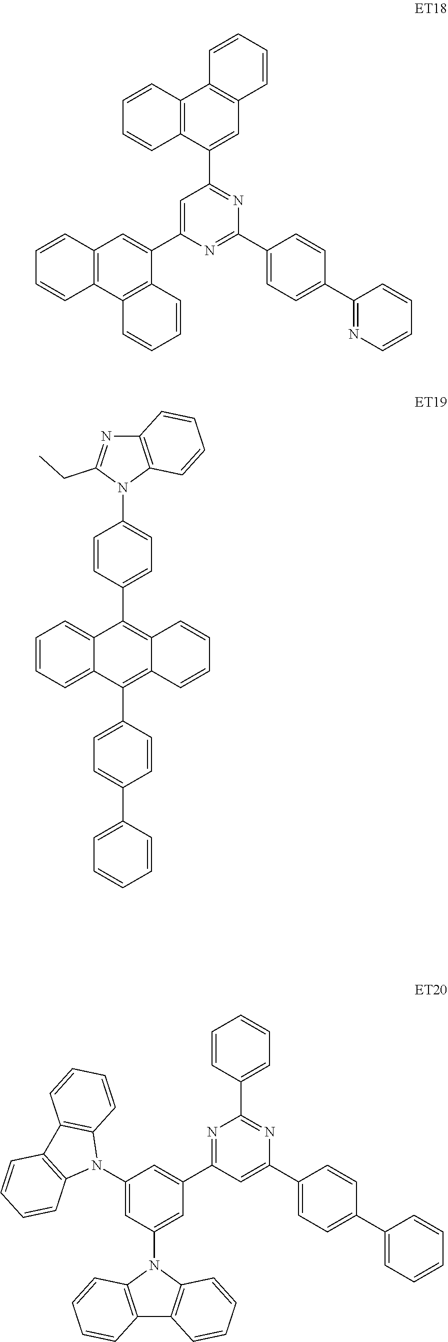 [SMILES: c1ccc(-c2ccc(-c3nc(-c4cc5ccccc5c5ccccc45)cc(-c4cc5ccccc5c5ccccc45)n3)cc2)nc1 ; CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

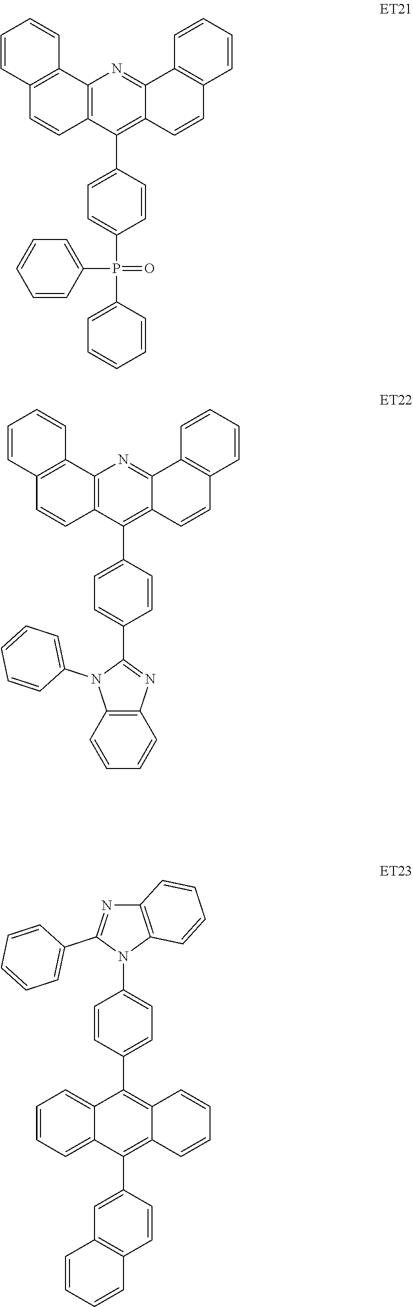 [SMILES: O=P(c1ccccc1)(c1ccccc1)c1ccc(-c2c3ccc4ccccc4c3nc3c2ccc2ccccc23)cc1 ; c1ccc(-n2c(-c3ccc(-c4c5ccc6ccccc6c5nc5c4ccc4ccccc45)cc3)nc3ccccc32)cc1 ; c1ccc(-c2nc3ccccc3n2-c2ccc(-c3c4ccccc4c(-c4ccc5ccccc5c4)c4ccccc34)cc2)cc1]

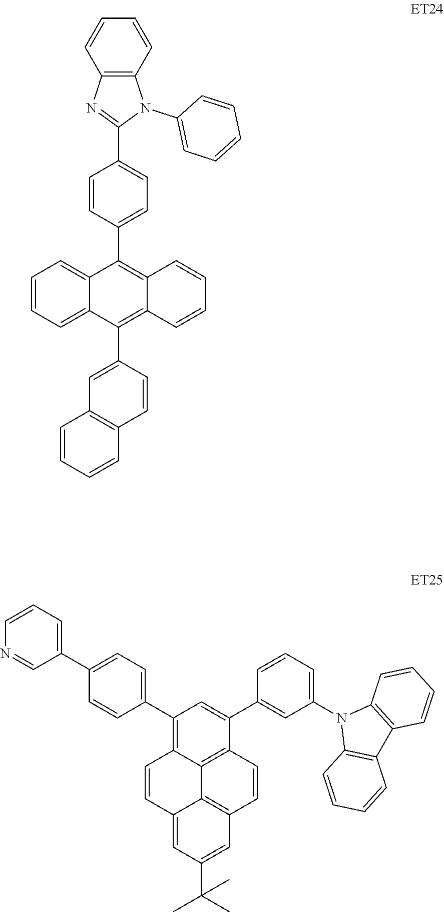 [SMILES: c1ccc(-n2c(-c3ccc(-c4c5ccccc5c(-c5ccc6ccccc6c5)c5ccccc45)cc3)nc3ccccc32)cc1 ; CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be about 100 Å to about 1,000 Å, for example, about 150 Å to about 500 Å. When the thickness of the electron transport layer is within these ranges, satisfactory electron transporting characteristics may be obtained without a substantial increase in driving voltage.

The electron transport layer may include a metal-containing material in addition to the material as described above.

The metal-containing material may include a Li complex. The Li complex may include, for example, Compound ET-D1 or ET-D2:

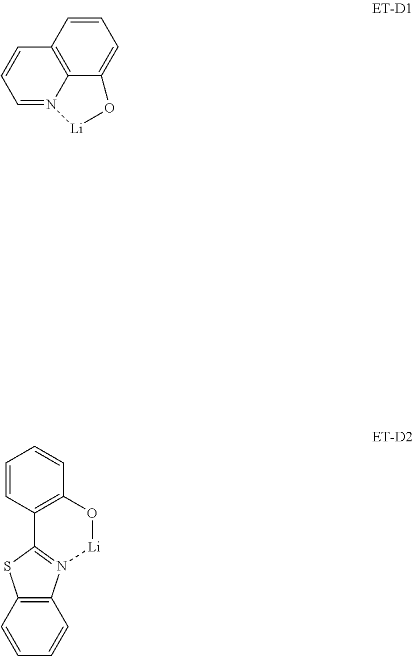

The electron transport region may also include an electron injection layer that promotes the flow of electrons from the second electrode 19 thereinto.

The electron injection layer may include LiF, NaCl, CsF, Li₂O, BaO, Yb, Compound ET-D1, Compound ET-D2, or a combination thereof.

A thickness of the electron injection layer may be about 1 Å to about 100 Å, and, for example, about 3 Å to about 90 Å. When the thickness of the electron injection layer is within these ranges, satisfactory electron injection characteristics may be obtained without a substantial increase in driving voltage.

The second electrode 19 may be arranged on the organic layer 15. The second electrode 19 may be a cathode. A material for forming the second electrode 19 may be metal, an alloy, an electrically conductive compound, or a combination thereof, which have a relatively low work function. For example, the material for forming the second electrode 19 may be Li, Mg, Al, Ag, Al—Li, Ca, Mg—In, Mg—Ag, or the like. To manufacture a top-emission type light-emitting device, various modifications are possible, and for example, a transmissive electrode formed using ITO or IZO may be used as the second electrode 19.

Hereinbefore, the light-emitting device 10 according to one or more embodiments has been described in connection with the FIGURE, but embodiments are not limited thereto.

For example, the light-emitting device may be included in an electronic apparatus. Thus, another aspect provides an electronic apparatus including the light-emitting device. The electronic apparatus may include, for example, a display, an illumination, a sensor, or the like.

The term “C₁-C₆₀ alkyl group” as used herein refers to a linear or branched saturated aliphatic hydrocarbons monovalent group having 1 to 60 carbon atoms, and the term “C₁-C₆₀ alkylene group” as used herein refers to a divalent group having the same structure as the C₁-C₆₀ alkyl group.

Non-limiting examples of the C₁-C₆₀ alkyl group, the C₁-C₂₀ alkyl group, and/or the C₁-C₁₀ alkyl group are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with at least one of methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or a combination thereof. For example, Formula 9-33 is a branched C₆ alkyl group, and an example thereof is a tert-butyl group that is substituted with two methyl groups.

The term “C₁-C₆₀ alkoxy group” as used herein refers to a monovalent group represented by -SA₁₀₁ (wherein A₁₀₁ is the C₁-C₆₀ alkyl group), and non-limiting examples thereof are a methoxy group, an ethoxy group, a propoxy group, a butoxy group, and a pentoxy group.

The term “C₁-C₆₀ alkylthio group” as used herein refers to a monovalent group represented by -SA₁₀₁ (wherein A₁₀₁ is the C₁-C₆₀ alkyl group).

The term “C₂-C₆₀ alkenyl group” as used herein refers to a hydrocarbon group formed by substituting at least one carbon-carbon double bond in the middle or at the terminus of the C₂-C₆₀ alkyl group, and non-limiting examples thereof are an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆o alkynyl group” as used herein refers to a hydrocarbon group formed by substituting at least one carbon-carbon triple bond in the middle or at the terminus of the C₂-C₆₀ alkyl group, and non-limiting examples thereof are an ethynyl group and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the term “C₃-C₁₀ cycloalkylene group” as used herein refers to a divalent group having the same structure as the C₃-C₁₀ cycloalkyl group.

Non-limiting examples of the C₃-C₁₀ cycloalkyl group are a cyclopropyl group, a cyclobutyl group, a cyclopentyl, cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group.

The term “C₁-C₁₀ heterocycloalkyl group” as used herein refers to a saturated monovalent cyclic group that includes at least one heteroatom selected from N, O, P, Si, S, Se, Ge, and B as a ring-forming atom(s) and 1 to 10 carbon atoms as ring forming atom(s), and the term C₁-C₁₀ heterocycloalkylene group” as used herein refers to a divalent group having the same structure as the C₁-C₁₀ heterocycloalkyl group.

Non-limiting examples of the C₁-C₁₀ heterocycloalkyl group are a silolanyl group, a silinanyl group, a tetrahydrofuranyl group, a tetrahydro-2H-pyranyl group, and a tetrahydrothiophenyl group.

The term “C₃-C₁₀ cycloalkenyl group” as used herein refers to a monovalent monocyclic group that includes 3 to 10 carbon atoms and at least one carbon-carbon double bond in the ring thereof and has no aromaticity, and non-limiting examples thereof are a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that includes at least one heteroatom selected from N, O, P, Si, S, Se, Ge, and B as a ring-forming atom, 1 to 10 carbon atoms as ring forming atom(s), and at least one carbon-carbon double bond in the ring thereof. Non-limiting examples of the C₁-C₁₀ heterocycloalkenyl group are a 2,3-dihydrofuranyl group and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group are a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₇-C₆₀ alkyl aryl group” as used herein refers to a C₆-C₆₀ aryl group substituted with at least one C₁-C₆₀ alkyl group. The term “C₇-C₆₀ aryl alkyl group” as used herein refers to a C₁-C₆₀ alkyl group substituted with at least one C₆-C₆₀ aryl group.

The term “C₁-C₆₀ heteroaryl group” as used herein refers to a monovalent group that includes at least one heteroatom selected from N, O, P, Si, S, Se, Ge, and B as a ring-forming atom and a cyclic aromatic system having 1 to 60 carbon atoms as ring forming atom(s), and the term “C₁-C₆₀ heteroarylene group” as used herein refers to a divalent group having the same structure has the C₁-C₆₀ heteroaryl group described herein. Non-limiting examples of the C₁-C₆₀ heteroaryl group are a pyridinyl group, a pyrimidinyl group, a pyrazinyl group, a pyridazinyl group, a triazinyl group, a quinolinyl group, and an isoquinolinyl group. When the C₆-C₆₀ heteroaryl group and the C₆-C₆₀ heteroarylene group each include two or more rings, the rings may be fused to each other.

The term “C₂-C₆₀ alkyl heteroaryl group” as used herein refers to a C₁-C₆₀ heteroaryl group substituted with at least one C₁-C₆₀ alkyl group. The term “C₂-C₆₀ heteroaryl alkyl group” as used herein refers to a C₁-C₆₀ alkyl group substituted with at least one C₁-C₆₀ heteroaryl group.

The term “C₆-C₆₀ aryloxy group” as used herein indicates -OA₁₀₂ (wherein A₁₀₂ is the C₆-C₆₀ aryl group), and the term “C₆-C₆₀ arylthio group” as used herein indicates -SA₁₀₃ (wherein A₁₀₃ is the C₆-C₆₀ aryl group).

The term “C₁-C₆₀ heteroaryloxy group” as used herein indicates -OA_{102′} (wherein A_{102′} is the C₁-C₆₀ heteroaryl group), and the term “C₁-C₆₀ heteroarylthio group” as used herein indicates -SA_{103′} (wherein A_{103′} is the C₁-C₆₀ heteroaryl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. A non-limiting example of the monovalent non-aromatic condensed polycyclic group is a fluorenyl group. The term “divalent non-aromatic condensed polycyclic group” as used herein refers to a divalent group having the same structure as the monovalent non-aromatic condensed polycyclic group described herein.

The term “monovalent non-aromatic condensed heteropolycyclic group” as used herein refers to a monovalent group (for example, having 1 to 60 carbon atoms) having two or more rings condensed to each other, at least one heteroatom selected from N, O, P, Si, S, Se, Ge, and B, other than carbon atoms, as a ring-forming atom(s), and no aromaticity in its entire molecular structure. A non-limiting example of the monovalent non-aromatic condensed heteropolycyclic group is a carbazolyl group. The term “divalent non-aromatic condensed heteropolycyclic group” as used herein refers to a divalent group having the same structure as the monovalent non-aromatic condensed heteropolycyclic group described above.

The term “C₅-C₃₀ carbocyclic group” as used herein refers to a saturated or unsaturated cyclic group having, as ring-forming atoms, 5 to 30 carbon atoms only and no heteroatoms in the cyclic group. The C₅-C₃₀ carbocyclic group may be a monocyclic group or a polycyclic group. Non-limiting examples of the “C₅-C₃₀ carbocyclic group (unsubstituted or substituted with at least one R₁₀ₐ)” as used herein are an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, and a fluorene group (each unsubstituted or substituted with at least one R₁₀ₐ).

The term “C₁-C₃₀ heterocyclic group” as used herein refers to a saturated or unsaturated cyclic group having, as a ring-forming atom(s), at least one heteroatom selected from N, O, P, Si, S, Se, Ge, and B other than 1 to 30 carbon atom(s) as ring-forming atom(s). The C₁-C₃₀ heterocyclic group may be a monocyclic group or a polycyclic group. Non-limiting examples of the “C₁-C₃₀ heterocyclic group (unsubstituted or substituted with at least one R₁₀ₐ)” as used herein are a thiophene group, a furan group, a pyrrole group, a silole group, borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group (each unsubstituted or substituted with at least one R₁₀ₐ).

Non-limiting examples of the “C₅-C₃₀ carbocyclic group” and “C₁-C₃₀ heterocyclic group” as used herein are i) a first ring, ii) a second ring, iii) a condensed ring in which two or more first rings are condensed with each other, iv) a condensed ring in which two or more second rings are condensed with each other, or v) a condensed ring in which at least one first ring is condensed with at least one second ring,

wherein the first ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and

the second ring may be an adamantane group, a norbornane group, a norbornene group, a piperidine group, a cyclohexane group, a cyclohexene group, a benzene group, a pyridine group, a pyrimidine group, a pyrazine group, a pyridazine group, or a triazine group.

The terms “fluorinated C₁-C₆₀ alkyl group (or fluorinated C₁-C₂₀ alkyl group or the like)”, “fluorinated C₃-C₁₀ cycloalkyl group”, “fluorinated C₁-C₁₀ heterocycloalkyl group,” and “fluorinated phenyl group” respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one fluoro group. For example, the term “fluorinated Ci alkyl group (that is, a fluorinated methyl group)” includes —CF₃, —CF₂H, and —CFH₂. The “fluorinated C₁-C₆₀ alkyl group (or fluorinated C₁-C₂₀ alkyl group or the like)”, “the fluorinated C₃-C₁₀ cycloalkyl group”, “the fluorinated C₁-C₁₀ heterocycloalkyl group”, or “the fluorinated phenyl group” may be i) a fully fluorinated C₁-C₆₀ alkyl group (or a fully fluorinated C₁-C₂₀ alkyl group or the like), a fully fluorinated C₃-C₁₀ cycloalkyl group, a fully fluorinated C₁-C₁₀ heterocycloalkyl group, or a fully fluorinated phenyl group, wherein, in each group, all hydrogen included therein are substituted with a fluoro group, or ii) a partially fluorinated C₁-C₆₀ alkyl group (or, a partially fluorinated C₁-C₂₀ alkyl group, or the like), a partially fluorinated C₃-C₁₀ cycloalkyl group, a partially fluorinated C₁-C₁₀ heterocycloalkyl group, or partially fluorinated phenyl group, wherein, in each group, all hydrogen included therein are not substituted with a fluoro group.

The terms “deuterated C₁-C₆₀ alkyl group (or deuterated C₁-C₂₀ alkyl group or the like)”, “deuterated C₃-C₁₀ cycloalkyl group”, “deuterated heterocycloalkyl group,” and “deuterated phenyl group” respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one deuterium. For example, the “deuterated Ci alkyl group (that is, deuterated methyl group)” may include —CD₃, —CD₂H, and —CDH₂, and examples of the “deuterated C₃-C₁₀ cycloalkyl group” are Formula 10-501 or the like. The “deuterated C₁-C₆₀ alkyl group (or deuterated C₁-C₂₀ alkyl group or the like)”, “the deuterated C₃-C₁₀ cycloalkyl group”, “the deuterated heterocycloalkyl group”, or “the deuterated phenyl group” may be i) a fully deuterated C₁-C₆₀ alkyl group (or, a fully deuterated C₁-C₂₀ alkyl group or the like), a fully deuterated C₃-C₁₀ cycloalkyl group, a fully deuterated heterocycloalkyl group, or a fully deuterated phenyl group, in which, in each group, all hydrogen included therein are substituted with deuterium, or ii) a partially deuterated C₁-C₆₀ alkyl group (or, a partially deuterated C₁-C₂₀ alkyl group or the like), a partially deuterated C₃-C₁₀ cycloalkyl group, a partially deuterated heterocycloalkyl group, or a partially deuterated phenyl group, in which, in each group, all hydrogen included therein are not substituted with deuterium.

The term “(C₁-C₂₀ alkyl)‘X’ group” as used herein refers to a ‘X’ group that is substituted with at least one C₁-C₂₀ alkyl group. For example, the term “(C₁-C₂₀ alkyl)C₃-C₁₀ cycloalkyl group” as used herein refers to a C₃-C₁₀ cycloalkyl group substituted with at least one C₁-C₂₀ alkyl group, and the term “(C₁-C₂₀ alkyl)phenyl group” as used herein refers to a phenyl group substituted with at least one C₁-C₂₀ alkyl group. An example of the term (C₁ alkyl)phenyl group is a toluyl group.

The terms “an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, and an azadibenzothiophene 5,5-dioxide group” respectively refer to heterocyclic groups having the same backbones as “an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluoren-9-one group, and a dibenzothiophene 5,5-dioxide group,” in which, in each group, at least one carbon atom from among ring-forming carbon atoms is substituted with nitrogen.

At least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may be:

deuterium, —F, —Cl, —Br, —I, —SF₅, —CD₃, —CD₂H, —CDH₂, —CF₃, —CF₂H, —CFH₂, a hydroxyl group, a cyano group, a nitro group, a C₁-C₆₀ alkyl group, a C₂-C₆₀ alkenyl group, a C₂-C₆o alkynyl group, a C₁-C₆₀ alkoxy group, or a C₁-C₆₀ alkylthio group;

a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, a C₁-C₆₀ alkyl group, a C₂-C₆₀ alkenyl group, a C₂-C₆₀ alkynyl group, a C₁-C₆o alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;

—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉), or a combination thereof.

As used herein, and unless indicated otherwise, Q₁ to Q₉, Q₁₁ to Q₁₉, Q₂₁ to Q₂₉, and Q₃₁ to Q₃₉ may each independently be:

hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group.

For example, Q₁ to Q₉, Q₁₁ to Q₁₉, Q₂₁ to Q₂₉, and Q₃₁ to Q₃₉ as used herein may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, a C₁-C₁₀ alkyl group, a phenyl group, or a combination thereof.

Hereinafter, a light-emitting device according to one or more embodiments are described in further detail with reference to Examples. However, the present subject matter is not limited thereto.

### EXAMPLES

### Synthesis Example 1 (Compound Pt(1) or Compound 25 of [Group 1-3])

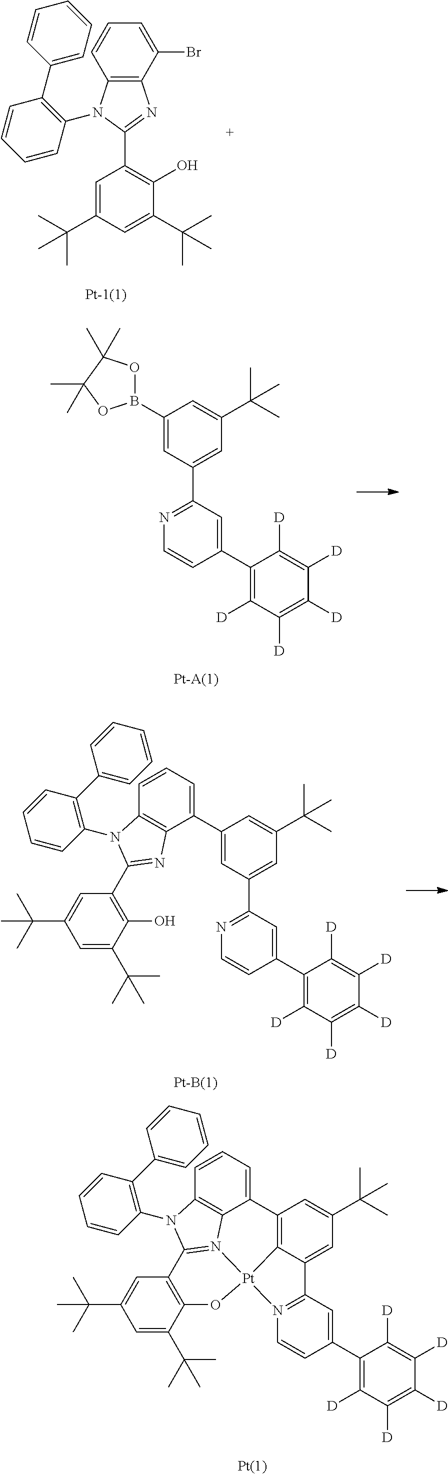

### Synthesis of Compound Pt-B(1)

Compound Pt-A(1) (2.2 grams (g), 5.2 millimoles (mmol)), Compound Pt-1(1) (3.5 g, 6.3 mmol), tetrakis(triphenylphosphine)palladium(0) (0.4 g, 0.4 mmol), and potassium carbonate (2.2 g, 15.7 mmol) were mixed with 60 mL of a mixture including tetrahydrofuran (THF) and deionized (DI) water at a volume ratio of 3:1, and the resultant mixed solution was heated at reflux for 12 hours. The obtained result was allowed to cool to room temperature, and the precipitate was removed therefrom by filtration to obtain a filtrate. The filtrate was then washed with ethyl acetate (EA) and DI water, and purification was performed using column chromatography (EA/hexane (Hex) 8%-12%) to complete the production of Compound Pt-B(1) (3.4 g, yield of 85%).

### Synthesis of Compound Pt(1)

Compound Pt-B(1) (3.2 g, 4.2 mmol) and K₂PtCl₄ (2.1 g, 5.0 mmol) were mixed with 70 mL of a mixture including 60 mL of acetic acid and 10 mL of DI water, and the resultant mixed solution was heated at reflux for 6 hours. The obtained result was allowed to cool to room temperature, and the precipitate was removed therefrom by filtration to obtain a filtrate. The filtrate was dissolved in methylene chloride (MC) and then washed with DI water. Subsequently, purification using column chromatography (MC 35%/Hex 65%) was performed thereon to complete the production of Compound Pt(1) (1.53 g, yield of 38%).

High resolution mass spectrometry using matrix assisted laser desorption ionization (HRMS (MALDI)) calculated for C₅₄H₄₆D₅N₃OPt: m/z 957.3994 grams per mole (g/mol), found: 957.3988 g/mol.

### Synthesis Example 2 (Compound Pt(2) or Compound 132 of [Group 1-3])

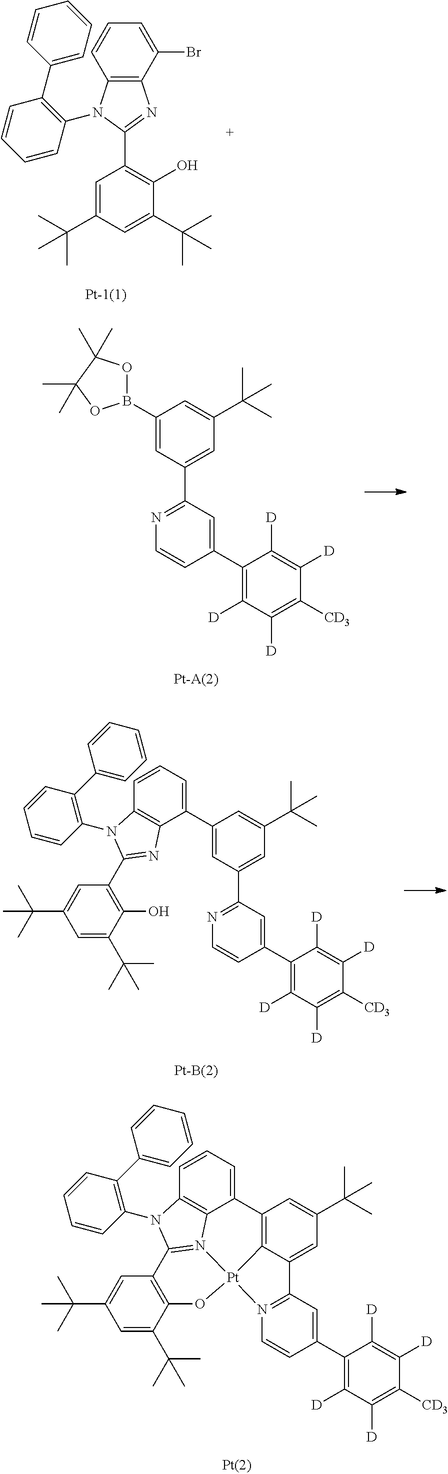

### Synthesis of Compound Pt-B(2)

Compound Pt-B(2) (3.1 g, yield of 79%) was obtained in a similar manner as in the synthesis of Compound Pt-B(1) of Synthesis Example 1, except that Compound Pt-A(2) was used instead of Compound Pt-A(1).

### Synthesis of Compound Pt(2)

Compound Pt(2) (1.7 g, yield of 43%) was obtained in a similar manner as in the synthesis of Compound Pt(1) of Synthesis Example 1, except that Compound Pt-B(2) was used instead of Compound Pt-B(1).

HRMS (MALDI) calculated for C₅₅H₄₆D₇N₃OPt: m/z 973.4276 g/mol, found: 973.4280 g/mol.

### Synthesis Example 3 (Compound Pt(3) or Compound 4 of [Group 1-4])

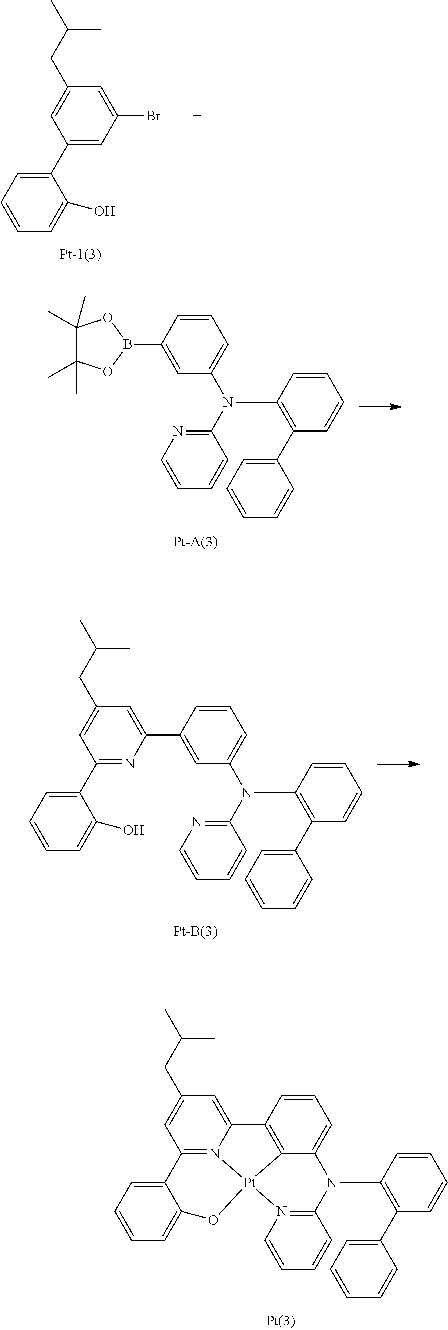

### Synthesis of Compound Pt-B(3)

Compound Pt-B(3) (3.23 g, yield of 82%) was obtained in a similar manner as in the synthesis of Compound Pt-B(1) of Synthesis Example 1, except that Compound Pt-1(3) was used instead of Compound Pt-1(1) and Compound Pt-A(3) was used instead of Compound Pt-A(1).

### Synthesis of Compound Pt(3)

Compound Pt(3) (1.53 g, yield of 39%) was obtained in a similar manner as in the synthesis of Compound Pt(1) of Synthesis Example 1, except that Compound Pt-B(3) was used instead of Compound Pt-B(1).

HRMS (MALDI) calculated for C₃₈H₃₁N₃OPt: m/z 740.2115 g/mol, found: 740.2130 g/mol.

### Synthesis Example 4 (Compound Ir-1 or Compound 16 of [Group 2-1])

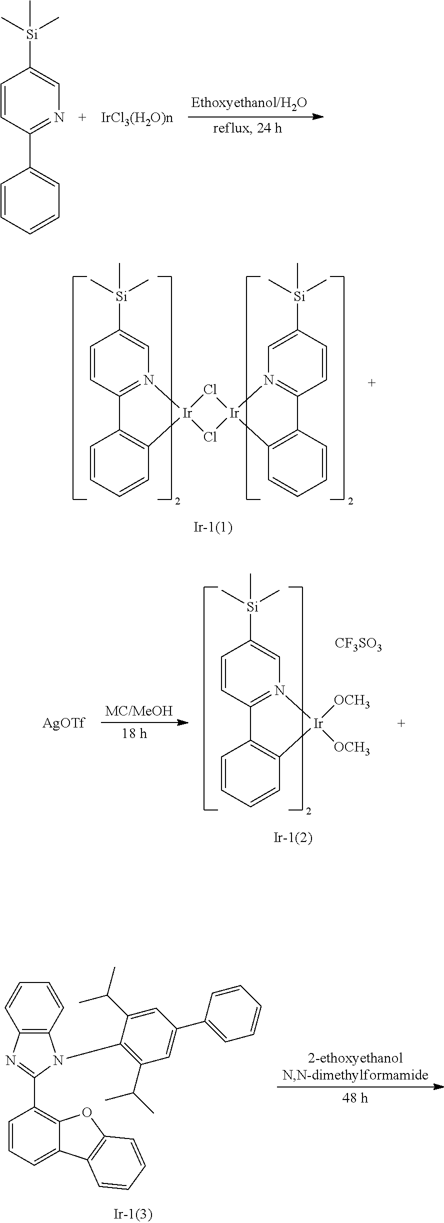

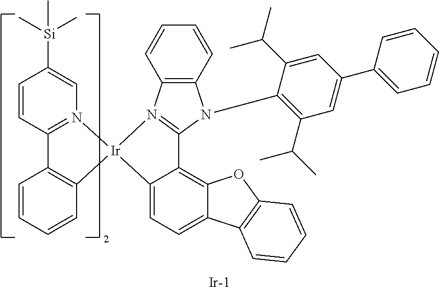

### Synthesis of Compound Ir-1(1)

2-phenyl-5-(trimethylsilyl)pyridine (7.5 g, 33.1 mmol) and iridium chloride hydrate (5.2 g, 14.7 mmol) were mixed with 120 mL of ethoxyethanol and 40 mL of DI water, and the resultant mixed solution was stirred and heated at reflux for 24 hours. Then, the temperature was allowed to lower to room temperature. The resulting solid was separated by filtration, washed sufficiently with DI water, methanol, and hexane, and the obtained solid was dried in a vacuum oven, to obtain 8.2 g (yield of 82%) of Compound Ir-1(1).

### Synthesis of Compound Ir-1(2)

Compound Ir-1(1) (1.6 g, 1.2 mmol) and 45 mL of MC were mixed, and a mixture of silver trifluoromethanesulfonate (silver triflate, AgOTf, 0.6 g, 2.3 mmol) and 15 mL of methanol (MeOH) was added thereto. Afterwards, the resultant mixture was stirred for 18 hours at room temperature while light was blocked with aluminum foil, and then filtered through a Celite plug to remove the resulting solid, and the filtrate was subjected to a reduced pressure to obtain a solid (Compound Ir1-2). Compound Ir1-2 was used in the next reaction without an additional purification process.

### Synthesis of Compound Ir-1

Compound Ir-1(2) (1.8 g, 2.15 mmol) and Compound Ir-1(3) (2-(dibenzo[b,d]furan-4-yl)-1-(3,5-diisopropyl-[1,1′-biphenyl]-4-yl)-1H-benzo[d]imidazole, 1.0 g, 2.04 mmol) were mixed with 10 mL of 2-ethoxyethanol and 10 mL of N, N-dimethylformamide, and the mixed solution was stirred and heated at reflux for 48 hours. Then, the temperature was allowed to lower to room temperature. The obtained mixture was subjected to a reduced pressure to obtain a solid, which was purified by column chromatography (eluents: MC and Hex) to obtain Compound Ir-1 (1.10 g, yield of 44%).

HRMS (MALDI) calculated for C₆₅H₆₃IrN₄OSi₂: m/z 1164.4170 g/mol, found: 1164.4171 g/mol.

### Synthesis Example 5 (Compound Ir-3 or Compound 116 of Group 2-4)

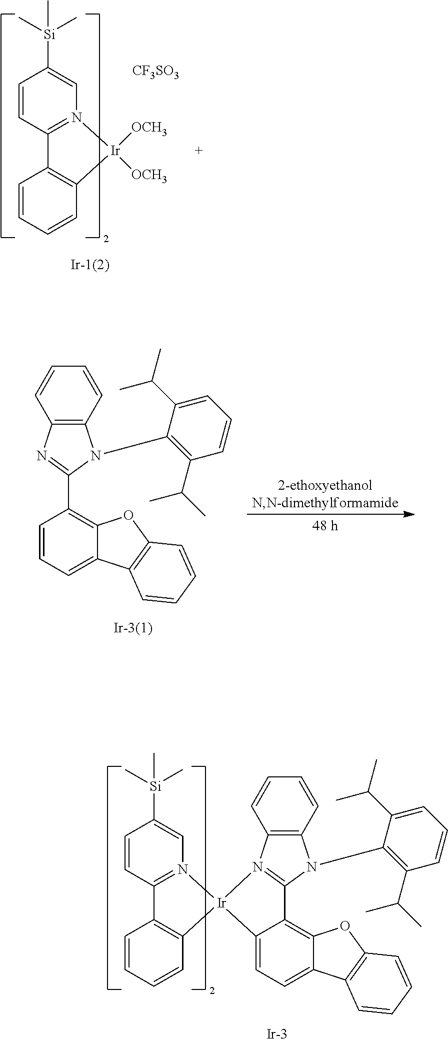

Compound Ir-1(2) (2.0 g, 2.3 mmol) and Compound Ir-3(1) (2-(dibenzo[b,d]furan-4-yl)-1-(2,6-diisopropylphenyl)-1H-benzo[d]imidazole, 1.0 g, 2.2 mmol) were mixed with 10 mL of 2-ethoxyethanol and 10 mL of N,N-dimethylformamide, and the mixed solution was stirred and heated at reflux for 48 hours. Then, the temperature was allowed to lower to room temperature. The obtained mixture was subjected to a reduced pressure to obtain a solid, which was purified by column chromatography (eluents: MC and Hex) to obtain Compound Ir-3 (1.20 g, yield of 48%).

HRMS (MALDI) calculated for C₅₉H₅₉IrN₄OSi₂: m/z 1088.3857 g/mol, found: 1088.3858 g/mol.

### Evaluation Example 1

The dipole moment of Compound Pt(1) was calculated by optimizing the molecular structure of Compound Pt(1) by using the B3LYP/LanL2DZ function for the metal included in Compound Pt(1) and B3LYP/6-31G(D,P) function for the organic ligand and performing the DFT calculation using the Gaussian 16 program. Using a similar method as described above, the dipole moments of the remaining Pt-containing compounds and Ir-containing compounds in Table 1 were calculated, and the results are summarized in Table 1.

TABLE 1

| Compound | Dipole moment |
|---|---|
| No. | (debye) |
| Pt(1) | 2.0263 |
| Pt(2) | 2.470 |
| Pt(3) | 4.833 |
| Ir-1 | 5.3374 |
| Ir-3 | 5.4158 |
| Pt-C | 0.064 |
| Pt-D | 0.314 |
| Pt-E | 4.969 |
| Pt-F | 3.167 |
| Ir-C | 6.279 |
| Ir-D | 1.951 |

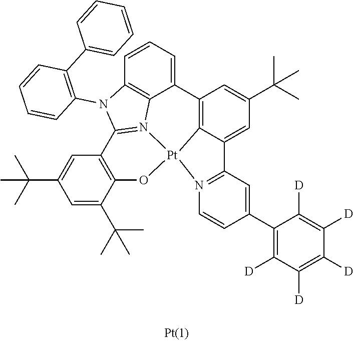

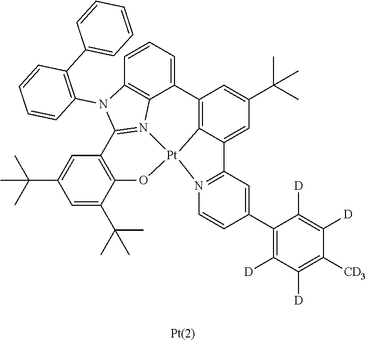

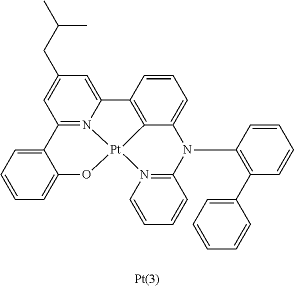

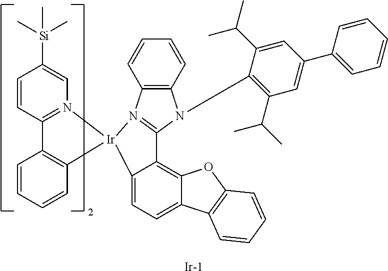

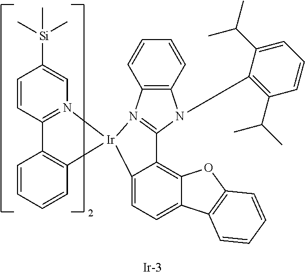

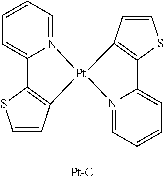

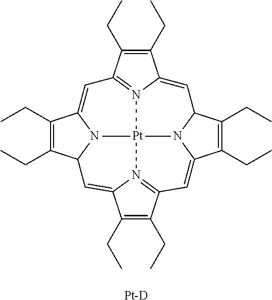

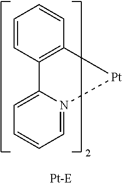

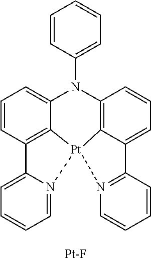

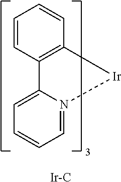

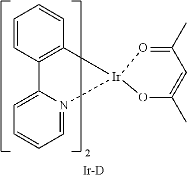

### Evaluation Example 2

On a quartz substrate, the compounds shown in Table 2 were vacuum co-deposited (at a pressure of 10⁻⁷ torr) at the weight ratios shown in Table 2 to manufacture 40 nm-thick films of Compounds Pt(1), Pt(2), Pt(3), Ir-1, Ir-3, Pt—C, Pt-D, Pt-E, Pt—F, Ir—C, and Ir-D.

Then, the emission spectrum for each of the films of Compounds Pt(1), Pt(2), Pt(3), Ir-1, Ir-3, Pt—C, Pt-D, Pt-E, Pt—F, Ir—C, and Ir-D was measured by using a Quantaurus-QY Absolute PL quantum yield spectrometer (produced by Hamamatsu Company, equipped with a xenon light source, a monochromator, a photonic multichannel analyzer, and an integrating sphere, and was programmed by the PLQY measurement software (Hamamatsu Photonics, Ltd., Shizuoka, Japan)). In the measurement, the excitation wavelength was scanned at 10 nm intervals between 320 nm and 380 nm, and a spectrum was measured using an excitation wavelength of 320 nm. Accordingly, Compounds Pt(1), Pt(2), Pt(3), Ir-1, Ir-3, Pt—C, Pt-D, Pt-E, Pt—F, Ir—C, and Ir-D were included in the corresponding Films Pt(1), Pt(2), Pt(3), Ir-1, Ir-3, Pt—C, Pt-D, Pt-E, Pt—F, Ir—C, and Ir-D, and were evaluated for the emission peak wavelength (λₘₐₓ, nm), and the results are shown in Table 2.

TABLE 2

| Film | Film composition (weight ratio) | λₘₐₓ (nm) |
|---|---|---|
| Pt(1) | H-H1:H-H2:Pt(1) (47.5:47.5:5) | 526 |
| Pt(2) | H-H1:H-H2:Pt(2) (47.5:47.5:5) | 522 |
| Pt(3) | H-H1:H-H2:Pt(3) (47.5:47.5:5) | 528 |
| Ir-1 | H-H1:H-H2:Ir-1 (47.5:47.5:5) | 526 |
| Ir-3 | H-H1:H-H2:Ir-3 (47.5:47.5:5) | 525 |
| Pt-C | H-H1:H-H2:Pt-C (47.5:47.5:5) | 584 |
| Pt-D | H-H1:H-H2:Pt-D (47.5:47.5:5) | 650 |
| Pt-E | H-H1:H-H2:Pt-E (47.5:47.5:5) | 501 |
| Pt-F | H-H1:H-H2:Pt-F (47.5:47.5:5) | 614 |
| Ir-C | H-H1:H-H2:Ir-C (47.5:47.5:5) | 513 |
| Ir-D | H-H1:H-H2:Ir-D (47.5:47.5:5) | 524 |

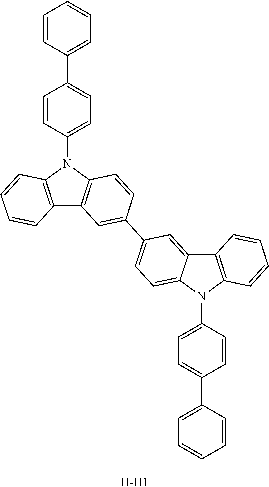 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; "H-H1"]

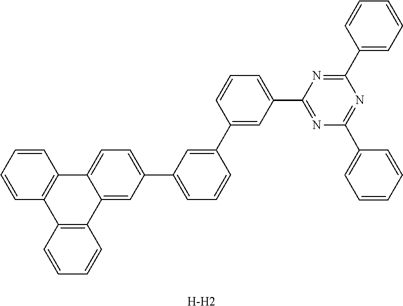 [SMILES: c1ccc(-c2nc(-c3ccccc3)nc(-c3cccc(-c4cccc(-c5ccc6c7ccccc7c7ccccc7c6c5)c4)c3)n2)cc1 ; "H-H2"]

### Manufacture of OLED 1

An ITO(as an anode)-patterned glass substrate was cut to a size of 50 millimeters (mm)×50 mm×0.5 mm, sonicated with isopropyl alcohol and DI water, each for 5 minutes, and then cleaned by exposure to ultraviolet (UV) rays and ozone for 30 minutes. The resultant ITO-patterned glass substrate was loaded onto a vacuum deposition apparatus.

HT3 and F6-TCNNQ were vacuum-deposited on the anode at a weight ratio of 98:2 to form a hole injection layer having a thickness of 100 Å, and then, HT3 was vacuum-deposited on the hole injection layer to form a hole transport layer having a thickness of 1,350 Å. H-H1 was vacuum-deposited on the hole transport layer to form an electron blocking layer having a thickness of 300 Å.

Subsequently, a host and a dopant were co-deposited at a weight ratio of 88:12 on the electron blocking layer to form an emission layer having a thickness of 400 Å. As the host, H-H1 and H-H2 were used at a weight ratio of 1:1, and as the dopant, the first compound and the second compound shown in Table 3 were used at the weight ratio of 1:1.

Then, ET3 and ET-D1 were co-deposited at a volume ratio of 50:50 on the emission layer to form an electron transport layer having a thickness of 350 Å, ET-D1 was vacuum-deposited on the electron transport layer to form an electron injection layer having a thickness of 10 Å, and Al was vacuum-deposited on the electron injection layer to form a cathode having a thickness of 1,000 Å, thereby completing the manufacture of an organic light-emitting device.

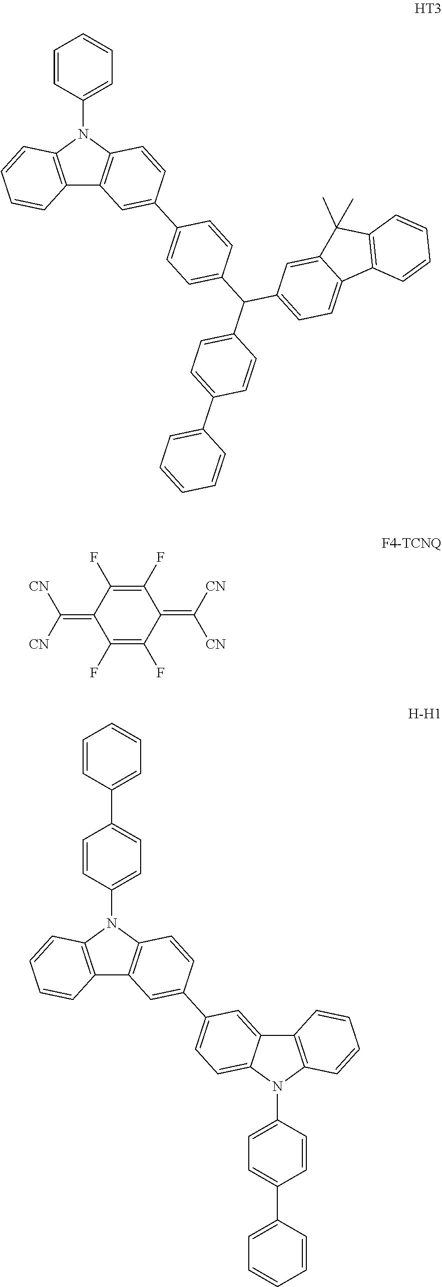

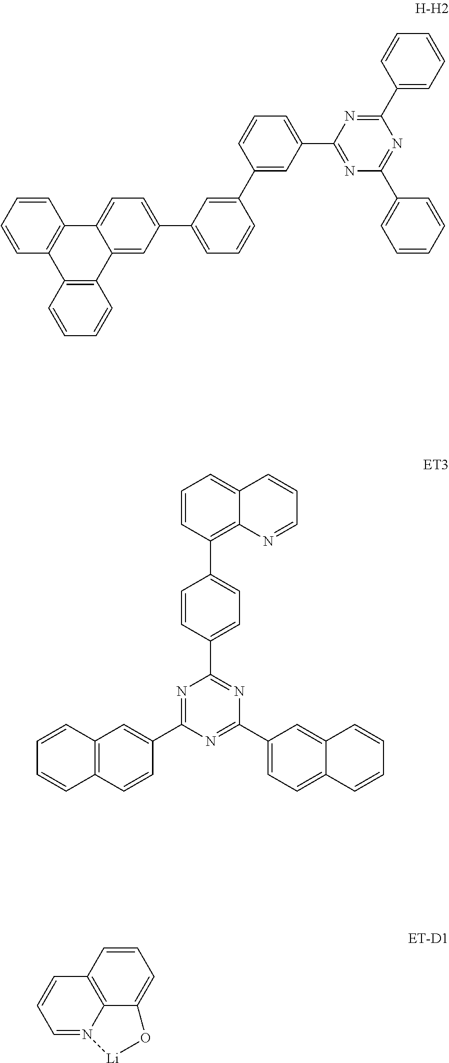

### Manufacture of OLEDs 2 to 4 and A to E

Organic Light-emitting devices were manufactured in a similar manner as in the manufacture of OLED 1, except those corresponding compounds shown in Table 3 were used as a dopant in forming an emission layer.

### Evaluation Example 3

For the OLEDs 1 to 4 and A to E, the driving voltage (V), the emission peak wavelength (λₘₐₓ) (nm), the maximum value of external quantum efficiency (Max EQE) (%), and the lifespan (LT₉₇) (hr) were evaluated, and the results are shown in Table 3. A current-voltage meter (Keithley 2400) and a luminance meter (Topcon SR3) were used as apparatuses for evaluation, and the lifespan (T₉₇) (at 18,000 candela per square meter, cd/m² or nits) was obtained by measuring the amount of time that elapsed until luminance was reduced to 97% of the initial luminance of 100%, and the results are expressed as relative values. For reference, the dipole moments and the emission peak wavelengths (λₘₐₓ) of the compounds used as the dopants in OLEDs 1 to 4 and C to E are summarized in Table 4.

TABLE 3

| | Dopant in emission layer | | Driving | | Max | LT₉₇ |
|---|---|---|---|---|---|---|
| | First | Second | voltage | λₘₐₓ | EQE | (Relative |
| | compound | compound | (V) | (nm) | (%) | value, %) |
| OLED 1 | Pt(1) | Ir-1 | 4.3 | 531 | 26.7 | 150 |
| OLED 2 | Pt(2) | Ir-1 | 4.3 | 531 | 26.5 | 142 |
| OLED 3 | Pt(1) | Ir-3 | 4.32 | 530 | 26.0 | 131 |
| OLED 4 | Pt(3) | Ir-1 | 4.35 | 531 | 25.5 | 100 |
| OLED A | Ir-1 | | 4.6 | 531 | 24.6 | 100 |
| OLED B | Pt(1) | | 4.2 | 526 | 25.1 | 20 |
| OLED C | Pt-C | Ir-C | 5.5 | 584 | 5 | <1 |
| OLED D | Pt-D | Ir-C | 5.9 | 650 | 4 | <1 |
| OLED E | Pt-E | Ir-C | 5.2 | 515 | 10 | <1 |
| OLED F | Pt-F | Ir-D | 5.5 | 614 | 15.4 | <10 |

TABLE 4

| | Dopant in emission layer | | | | | |
|---|---|---|---|---|---|---|
| | | | | Second compound | | |
| | First compound | | | | | Emission |
| | | Dipole | | | Dipole | peak |
| | | moment | λₘₐₓ | | moment | wavelength |
| | No. | (debye) | (nm) | No. | (debye) | (nm) |
| OLED 1 | Pt(1) | 2.0263 | 526 | Ir-1 | 5.3374 | 526 |
| OLED 2 | Pt(2) | 2.470 | 522 | Ir-1 | 5.3374 | 526 |
| OLED 3 | Pt(1) | 2.0263 | 526 | Ir-3 | 5.4158 | 525 |
| OLED 4 | Pt(3) | 4.833 | 528 | Ir-1 | 5.3374 | 526 |
| OLED C | Pt-C | 0.064 | 584 | Ir-C | 6.279 | 513 |
| OLED D | Pt-D | 0.314 | 650 | Ir-C | 6.279 | 513 |
| OLED E | Pt-E | 4.969 | 501 | Ir-C | 6.279 | 513 |
| OLED F | Pt-F | 3.167 | 614 | Ir-D | 1.951 | 524 |

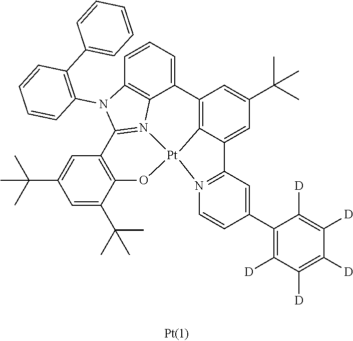

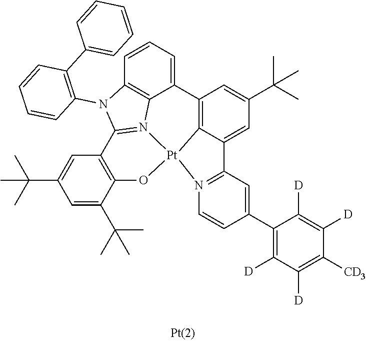

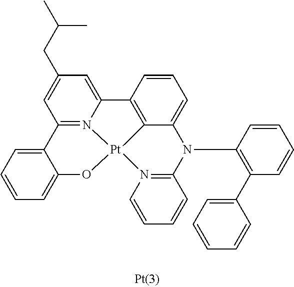

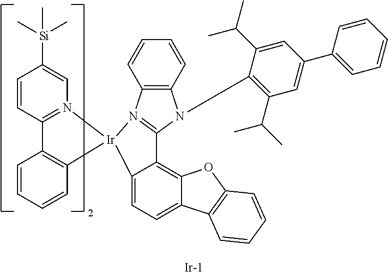

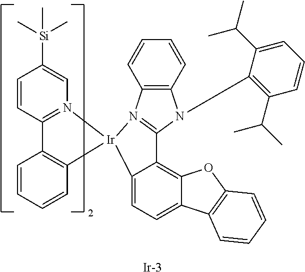

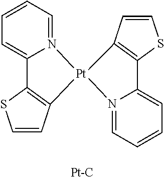

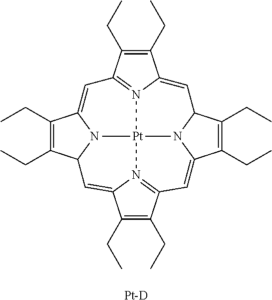

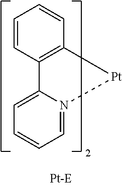

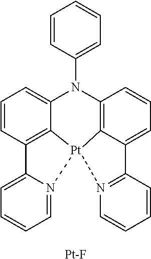

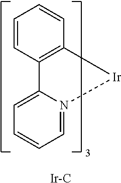

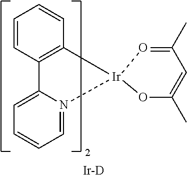

Referring to Table 3, it was confirmed that each of OLEDs 1 to 4 emitted green light and had improved driving voltage, improved EQE, and improved lifespan characteristics as compared to those of OLEDs A to E.

According to the one or more exemplary embodiments described herein, an electronic device, for example, a light-emitting device, employing a composition may have improved driving voltage, improved external quantum efficiency, and improved lifetime characteristics.

It should be understood that one or more exemplary embodiments described herein should be considered in a descriptive sense and not for purposes of limitation. Descriptions of features or aspects within each exemplary embodiment should typically be considered as available for other similar features or aspects in other exemplary embodiments. While one or more exemplary embodiments have been described, and in some cases are described with reference to the FIGURE, it will be understood by those of ordinary skill in the art that various changes in form and details may be made therein without departing from the spirit and scope as defined by the following claims.

What is claimed is:

1. A composition, comprising:
a first compound; and
a second compound,
wherein
the first compound is an organometallic compound comprising platinum and a tetradentate ligand bound to the platinum,
the second compound is an organometallic compound comprising iridium,
μ(Pt) is about 0.5 debye to about 5.0 debye,
μ(Pt) is less than μ(Ir),
μ(Pt) is a dipole moment of the first compound,
μ(Ir) is a dipole moment of the second compound, and
each of μ(Pt) and μ(Ir) is calculated based on density functional theory.

2. The composition of claim 1, wherein μ(Pt) is about 1.5 debye to about 5.0 debye.

3. The composition of claim 1, wherein μ(Ir) is about 4.0 debye to about 9.0 debye.

4. The composition of claim 1, wherein μ(Ir)-μ(Pt) is about 0.3 debye to about 4.0 debye.

5. The composition of claim 1, wherein
the first compound emits a first light having a first spectrum, and λP(Pt) is an emission peak wavelength of the first spectrum,
the second compound emits a second light having a second spectrum, and λP(Ir) is an emission peak wavelength of the second spectrum,
λP(Pt) is evaluated from a first photoluminescence spectrum measured for a first film,
λP(Ir) is evaluated from a second photoluminescence spectrum measured for a second film,
the first film comprises the first compound,
the second film comprises the second compound, and
an absolute value of a difference between λP(Pt) and λP(Ir) is 0 nanometers to about 30 nanometers.

6. The composition of claim 5, wherein the absolute value of the difference between λP(Pt) and λP(Ir) is 0 nanometers to about 10 nanometers.

7. The composition of claim 5, wherein each of λP(Pt) and λP(Ir) is about 510 nanometers to about 540 nanometers.

8. The composition of claim 5, wherein each of λP(Pt) and λP(Ir) is about 540 nanometers to about 570 nanometers.

9. The composition of claim 1, wherein the first compound is an organometallic compound comprising:
a chemical bond between a carbon atom of the tetradentate ligand and platinum, and
a chemical bond between an oxygen atom of the tetradentate ligand and platinum.

10. The composition of claim 1, wherein
the second compound comprises a first ligand, a second ligand, and a third ligand, wherein:
the first ligand, the second ligand, and the third ligand are identical to each other,
the first ligand and the second ligand are identical to each other, and the second ligand and the third ligand are different from each other, or
the first ligand, the second ligand, and the third ligand are different from each other, and
each of the first ligand, the second ligand, and the third ligand comprises:
a bidentate ligand bound to the iridium of the second compound via two nitrogen atoms;
a bidentate ligand bound to iridium of the second compound via a nitrogen atom and a carbon atom; or
a bidentate ligand bound to iridium of the second compound via two carbon atoms.

11. A layer, comprising the composition of claim 1.

12. A light-emitting device, comprising:
a first electrode;
a second electrode; and
an organic layer arranged between the first electrode and the second electrode,
wherein the organic layer comprises an emission layer, and
wherein the organic layer comprises the composition of claim 1.

13. The light-emitting device of claim 12, wherein the emission layer comprises the composition.

14. The light-emitting device of claim 13, wherein
the emission layer comprises a host and a dopant,
the host does not comprise a transition metal, and
the dopant comprises the composition.

15. The light-emitting device of claim 14, wherein the host comprises a hole-transporting compound, an electron-transporting compound, a bipolar compound, or a combination thereof.

16. The light-emitting device of claim 13, wherein the emission layer emits a third light having a third spectrum, and λP(EML) is an emission peak wavelength of the third spectrum,
λP(EML) is evaluated from an electroluminescence spectrum of the light-emitting device, and
λP(EML) is about 510 nanometers to about 570 nanometers.

17. The light-emitting device of claim 13, wherein
the first compound emits a first light having a first spectrum, and λP(Pt) is an emission peak wavelength of the first spectrum,
the second compound emits a second light having a second spectrum, and λP(Ir) is an emission peak wavelength of the second spectrum,
the emission layer emits a third light having a third spectrum, and λP(EML) is an emission peak wavelength of the third spectrum,
λP(Pt) is evaluated from a first photoluminescence spectrum measured for a first film,
λP(Ir) is evaluated from a second photoluminescence spectrum measured for a second film,
the first film comprises the first compound,
the second film comprises the second compound, and
λP(EML) is evaluated from an electroluminescence spectrum of the light-emitting device, and
an absolute value of a difference between λP(Pt) and λP(Ir) is 0 nanometers to about 30 nanometers,
an absolute value of a difference between λP(EML) and λP(Pt) is 0 nanometers to about 30 nanometers, and
an absolute value of a difference between λP(EML) and λP(Ir) is 0 nanometers to about 30 nanometers.

18. The light-emitting device of claim 17, wherein
the absolute value of the difference between λP(Pt) and λP(Ir) is 0 nanometers to about 10 nanometers,
the absolute value of the difference between λP(EML) and λP(Pt) is 0 nanometers to about 10 nanometers, and
the absolute value of the difference between λP(EML) and λP(Ir) is 0 nanometers to about 10 nanometers.

19. The light-emitting device of claim 17, wherein
λP(Pt)=λP(Ir)=λP(EML),
λP(Pt)≤λP(Ir)<λP(EML),
λP(Pt)<λP(Ir)≤λP(EML),
λP(Ir)≤λP(Pt)<λP(EML), or
λP(Ir)<λP(Pt)≤λP(EML).

20. An electronic apparatus, comprising the light-emitting device of claim 12.
